(19) United States
(12) Patent Application Publication
(10) Pub. No.: US 2004/0050316 A1
(43) Pub. Date: Mar. 18, 2004

(54) Crystal structure

(76) Inventors: Richard John Bazin, County of Kent (GB); Graeme Arthur MacDonald, County of Kent (GB); Christopher Phillips, County of Kent (GB)

Correspondence Address: Gregg C. Benson, Pfizer Inc., Patent Department, MS 4159, Eastern Point Road, Groton, CT, 06340, US

(21) Appl. No.: 10/022,366

(22) Filed: Dec. 13, 2001

Related U.S. Application Data
(60) Provisional application No. 60/260,627, filed on Jan. 10, 2001.

(30) Foreign Application Priority Data
Dec. 13, 2000 (GB) 0030424.6

(51) Int. Cl. C30B 33/06

(52) U.S. Cl. 117/1

(57) ABSTRACT

A 2.2 Å crystal structure of rabbit AMP deaminase, an integral enzyme of purine nucleotide interconversion, has been determined, in an unligated state and with an inhibitor bound. The present invention further discloses the use of x-ray crystallographic data for identification and construction of possible therapeutic compounds in the treatment of various disease conditions. The sequence of rabbit AMP deaminase is also disclosed.

### CROSS REFERENCE TO RELATED APPLICATION

This application claims the benefit of U.K. Provisional Application No. 0030424.6, filed Dec. 13, 2000 and U.S. Provisional Application No. 60/260,627, filed Jan. 10, 2001.

### FIELD OF THE INVENTION

The present invention relates to crystals of adenosine monophosphate deaminase (AMPDA), and more particularly to the high-resolution structure of AMPDA obtained by X-ray diffraction. The invention further relates to the use of the three-dimensional structure so determined to identify, design or select compounds that bind to AMPDA or its active site.

### BACKGROUND OF THE INVENTION

AMP deaminase (AMPDA; EC 3.5.4.6) is an integral enzyme of purine nucleotide interconversion. The zinc dependent enzyme catalyses the irreversible hydrolysis of 5′ adenosine monophosphate (AMP) to form inosine monophosphate (IMP) and ammonia. This reaction represents a branch-point in the energy-generating adenylate catabolic pathway regulating the availability of adenosine nucleotides, including ATP, within the cell. The enzyme is a target e.g. for the treatment of ischemia-related diseases. Blocking the pathway reduces the depletion of the total adenine pool observed in ischemic tissues (Erion, M. D., et al. (1999) J. Am. Chem. Soc. 121, 308-319; Skladanowski, A. C. in Myocardial Energy Metabolism (ed. de Jong, J. W.) 53-65 (Dordrecht, 1998)), and thus the metabolically expensive requirement for the de novo synthesis of ATP. Patients with congestive heart failure (CHF) have been found to have a significantly longer survival period without heart transplant if they have a genetic deficiency in skeletal muscle AMPDA (Loh, E., et al. (1999) Circulation 99, 1422-1425); similarly, survival in patients with coronary artery disease (CAD) is improved if they have a common variant of the ampd1 gene, which encodes a truncated, inactive enzyme (Anderson, J. L. et al (2000) J. Am Coll Cardiol 36, 1248-1252). The therapeutic potential of specific AMPDA inhibitors is not limited to CHF and CAD, but extends to other diseases, including to all ischemia-related diseases. These include peripheral vascular disease and chronic obstructive pulmonary disease. As recently reported, AMPDA inhibitors could also be useful in Alzheimer's disease (Sims, B. et al. (1998) Neurobiol. Aging 19, 385-391).

AMPDA is a diverse, oligomeric, and highly regulated enzyme ubiquitous in eukaryotic cells. Multiple isoforms have been purified and characterised from rat and human tissues, which are encoded by transcripts from a multigene family (Morisaki, T., Sabina, R. L. & Holmes, E. W. (1990) J. Biol. Chem. 265, 11482-11486; Baush-Jurken, M. T., et al (1992) J. Biol. Chem. 267, 22407-22413). Three mammalian genes encoding AMP deaminase have been identified; ampd1, which encodes the isoenzyme expressed at high levels in skeletal muscle (M-AMPDA), ampd2 and ampd3 which are expressed in a wide range of tissues and are called the smooth and cardiac muscle isoenzymes (or L-AMPDA and E-AMPDA) respectively. Sequence analysis demonstrates that these isoenzymes have a highly conserved C-terminal domain and a smaller divergent N-terminal domain. The skeletal enzyme is closely associated with muscle fibers binding the myosin heavy chain and is regulated by a number of factors. ATP acts as an allosteric inhibitor. K⁺ ion concentration modulates the enzyme activity which has also been shown to increase under the mildly acidic (pH6.5) conditions found in exercising muscle (Sabina, R. L. & Malinke-Zizelman, D. K. (2000) Pharmacol. Ther. 87, 279-283; Ranieri-Raggi, M. & Raggi, A. (1990) Biochem. J. 272, 755-759; Ranieri-Raggi, M. & Raggi, A. (1980) Biochem. J. 189, 367-368; Ranieri-Raggi, M. & Raggi, A. (1979) FEBS Lett. 102, 59-63; Thakkar, J. K., et al (1993) Biochem. J. 290, 335-341; Hisatome, I., et al. (1998) Am J. Physiol. 275, C870-C881).

The purification of the enzyme from rabbit muscle has been reported by Smiley, K. L., Berry, A. J. & Suelter, C. H. ((1967) J. Biol. Chem. 242, 2502-2506). The protein is unstable and on storage the N-terminal domain (7 kDa) is removed, an effect that can be reproduced by limited trypsin proteolysis cleaving the enzyme after lysine 95 (Sabina, R. L. & Mahnke-Zizelman, D. K. (2000) Pharmacol. Ther. 87, 279-283). The C-terminal domain retains catalytic activity. However, in the truncated state the enzyme is less tightly regulated and ATP no longer inhibits the enzyme allosterically, indicating that the small N-terminal domain is regulatory and binds ATP. Enzyme has since been produced from a number of sources including chicken (Chilson, O. P., Kelly-Chilson, A. E. & Siegel, N. R. (1997) Comp. Biochem. Physiol. 116B, 371-377) and rat (Coffee, C. J. & Kofke, W. A. (1975), J. Biol. Chem. 250, 6653-6658) skeletal-muscle, while the human enzyme has been produced in a baculovirus expression system (Mahnke-Zizelman, D. K., Tullson, P. C. & Sabina, R. L. (1998) J. Biol. Chem. 273, 35118-35125). Like the rabbit enzyme, each of these proteins is unstable which has led to a range of molecular weights for the enzymes being reported and some debate over the oligomeric make-up of the protein. Trimers have been reported for the truncated form of the enzyme, but controlled limited proteolysis has demonstrated that the enzymes purified from mammalian skeletal muscle are most likely homo-tetramers of the truncated enzyme (Sabina, R. L. & Mahnke-Zizelman, D. K. (2000) Pharmacol. Ther. 87, 279-283).

Despite its early identification and purification, structural information on the enzyme is very limited. The hexagonal bipyramidal crystals obtained by Smiley, Berry & Suelter ((1967) J. Biol. Chem. 242, 2502-2506) are not suitable for X-ray crystallography, and the structure of the enzyme has not been elucidated. Sequence analysis by conventional techniques fails to identify any close homologues; however, an extensive analysis of amidohydrolase sequences using a combination of database searching, conserved functional properties and sequence threading techniques suggests that the enzyme may share the same fold, an ellipsoidal (βα)₈ barrel with a conserved metal binding site, as the urease and adenosine deaminase (ADA) family of proteins (Hohm, L. & Sander, C. (1997) Proteins 28, 72-82). In contrast, a second study has proposed that the catalytic C-terminal domain of AMPDA contains two pleckstrin homology (PH) domains, a prediction which is functionally supported by the observation that AMPDA binds phosphoinositides (Sims, B., et al. (1999) J. Biol. Chem. 274, 25701-25707).

Various AMPDA inhibitors have been identified; examples are coformycin (Nakamura H et al (1974) J. Am. Chem. Soc. 96, 4327-8), as well as inhibitors based around coformycin, (Erion, M. D. et al (1999) J. Am. Chem. Soc. 121, 308-319; Bookser, B. C. et al. (2000) J. Med. Chem. 43, 1495-1507), and a series of compounds as exemplified in WO 94/18200, including 3-(2′-(3″-carboxynaphthyl)ethyl)coformycin aglycone (compound 1p), herein called UK-384,858. AMPDA is also inhibited by alkylsulfonate compounds (Yoshino, M. & Murakami, K. (1998) Env Tox Pharmacol 5, 215-217). However, without the structure of the enzyme and detailed knowledge at the atomic level of how the inhibitors bind to the enzyme, the design and optimisation of such compounds is difficult.

### ASPECTS IF THE INVENTION

In a broad aspect, the invention relates to novel crystals of AMPDA which are of tetragonal form. Preferred embodiments include crystals

wherein the AMPDA consists of the catalytic domain,

wherein the AMPDA is from a mammal,

wherein the AMPDA is from a rabbit,

wherein the AMPDA has the sequence as in SEQ ID NO: 2 but starting at position Leu96;

wherein the crystal has been grown with citric acid as the precipitating agent;

wherein the crystal has been grown in the pH range of 7.80-8.20;

wherein the crystal has been grown in the presence of imidazole;

wherein the crystal has a space group P4₂2₁2;

wherein the crystal has unit cell dimensions of a=b=149 Å+/−3 Å, c=159 Å+/−3 Å, more preferably wherein the crystal has unit cell dimensions of a=b=148.7 Å, c=158.6 Å,

wherein there is a dimer of two AMPDA molecules in the asymmetric unit;

wherein two AMPDA dimers form tightly associated tetramers, each monomer having a (βα)₈ barrel fold, where the intersubunit contacts are almost exclusively made by the helices additional to the (βα)₈ barrel;

wherein the AMPDA has a Zn²⁺ coordination site involving residues His303, His305, His 572, and Asp649, with a further coordination site contributed by an activated water molecule required for catalysis;

wherein the active site of AMPDA is contained in a cleft formed by the additional helices between the first and second strand of the (βα)₈ barrel fold, and the helix immediately following the third strand;

wherein the AMPDA has a pocket which can accommodate the adenosine group of AMP, which pocket is formed by amino acid residues including, but not limited to, residues His305, Phe372, Phe375, Asp513, Glu575, His594, and Asp650;

wherein the AMPDA has a pocket which can accommodate the ribose and phosphate groups of AMP, which pocket is formed by amino acid residues including, but not limited to, residues His305, Ala306, Ala307, Ala308, Phe375, Asn376, Tyr379, Arg388, Lys393, Ser427, Tyr429, Pro460, Ile462, Val512, and Asp513;

which diffracts X-rays to 3.5 Å, preferably to 2.8 Å, 2.5 Å, or 2.2 Å resolution;

which has the atomic coordinates set out in Table 2, or a derivative set as expressed in any reference frame.

A preferred embodiment is a heavy atom derivative of the above mentioned crystals; preferably, the heavy atoms are lead, silver or xenon.

Further preferred embodiments are the above mentioned AMPDA crystals with inhibitors soaked in, more preferably wherein the inhibitors are AMPDA transition state analogues, preferably coformycin analogues, even more preferably wherein the inhibitor is coformycin or wherein the inhibitor is UK-384,858. A preferred embodiment of the invention is an AMPDA crystal with coformycin soaked in, having the atomic coordinates as set out in Table 3, or a derivative set as expressed in any reference frame; another preferred embodiment is an AMPDA crystal with UK-384,858 soaked in, having the atomic coordinates as set out in Table 4, or a derivative set as expressed in any reference frame.

A further embodiment of the invention is a crystal of AMPDA wherein the primary sequence of the AMPDA has 90%, preferably 95%, even more preferably 98% identity at amino acid level to the sequence shown in SEQ ID NO:2.

A further embodiment of the invention is the use of atomic coordinates obtained by X-ray diffraction studies of the above mentioned crystals for deriving the three-dimensional structure of AMPDA.

Preferred embodiments of the invention are the use of the three-dimensional structure of AMPDA so determined for computationally or otherwise evaluating the binding interactions of a chemical compound with AMPDA, preferably the active site of AMPDA; and for designing compounds, preferably inhibitors of AMPDA, capable of associating with the enzyme, or preferably with the active site of the enzyme.

A preferred embodiment is a compound evaluated or designed as described above.

Another embodiment of the invention is a method of selecting an AMPDA inhibitor from a group of potential AMPDA inhibitor compounds by creating a three-dimensional representation of the enzyme, preferably the active site cavity of AMPDA, as derived from the three-dimensional structure determined above, in a suitable computer program; displaying and superimposing the model of said test compound on the model of said enzyme, or preferably the active site of it, and assessing whether the test compound model fits the enzyme, or preferably its active site. The method can further comprise incorporating the test compound in a biological AMPDA activity assay, and determining whether the test compound inhibits AMPDA activity in this assay. A compound selected by such method is also an embodiment of the invention.

Further embodiments of the invention are pharmaceutical compositions of any of the compounds evaluated, designed, or selected as described above, as well as their use in the manufacture of a medicament for the treatment of diseases where AMPDA is implicated. These diseases include but are not limited to, ischemia-related diseases such as congestive heart failure, peripheral vascular disease, and chronic obstructive pulmonary disease. The diseases also include coronary artery disease (CAD) and Alzheimer's disease.

Another embodiment of the invention is the use of the atomic coordinates of AMPDA as mentioned above, or portions thereof, to solve a crystal form of a mutant, homologue, or co-complex of AMPDA, e.g. by molecular replacement or difference Fourier analysis, as well as the use of the atomic coordinates to produce a model of the three-dimensional structure of related enzymes.

A further embodiment of the invention is an isolated and/or purified polynucleotide comprising a polynucleotide encoding the polypeptide as set forth in SEQ ID NO: 2; a polynucleotide comprising a nucleotide sequence of SEQ ID NO: 1; a polynucleotide comprising a nucleotide sequence that has at least 91%, preferably 95%, even more preferably 98% identity t6 the polynucleotide mentioned above; a polynucleotide comprising a nucleotide sequence which is capable of hybridising to the polynucleotide mentioned above under high stringency conditions (washing with 0.1× SSC, 0.1% SDS at 65° C.); a complement to any of the polynucleotide mentioned above, or a polynucleotide fragment of any of these polynucleotides.

A further embodiment of the invention is a polypeptide having the deduced amino acid sequence translated from the polynucleotide sequence in SEQ ID NO: 1 and variants, fragments, homologues, analogues and derivatives thereof; or a polypeptide of SEQ ID NO: 2 and variants, fragments, homologues, analogues and derivatives thereof. A preferred embodiment is a polypeptide of SEQ ID NO: 2 but starting at position Leu96.

### DEFINITIONS

AMPDA: AMP deaminase (E.C. 3.5.4.6)—catalyzes the deamination of AMP to IMP as part of the purine catabolic pathway.

AMPDA catalytic domain: the C-terminal part of the enzyme, sufficient for catalytic activity (usually lacking the N-terminal 80-100 residues).

M-AMPDA, L-AMPDA and E-AMPDA isoenzymes: Products of different genes (ampd1, ampd2 and ampd3), but all encoding AMP deaminase, i.e. the same activity; the isoenzymes are differentially expressed in different tissues.

Polynucleotide: DNA or RNA in isolated form, made by recombinant or synthetic routes.

Polypeptide: interchangeable with the term protein, includes single-chain polypeptides as well as complexes of single-chain polypeptides linked by covalent or non-covalent means.

The terms “variant”, “homologue”, “fragment”, “analogue” or “derivative” in relation to the amino acid sequence for the polypeptide of the present invention include any substitution of, variation of, modification of, replacement of, deletion of or addition of one (or more) amino acid from or to the sequence providing the resultant polypeptide retains 90%, preferably 95%, even more preferably 98% sequence identity to the sequence shown in SEQ ID No:2. Sequence identity is determined by standard bioinformatics software tools such as Blast2 or Fasta, which generate an optimal alignment between two sequences and then calculate the % identity on this basis, using default parameters.

Mutant of AMPDA refers to AMPDA where changes in one or more amino acid residues have been introduced artificially by processes like site-directed mutagenesis, or where deletions or insertions have been introduced into the AMPDA sequence, whether or not the resulting proteins retain enzyme activity. It also refers to naturally occurring variants of AMPDA, whether or not they retain enzyme activity.

Related protein refers to a protein the structure of which has not yet been determined, which displays significant sequence similarity (>30% sequence identity at protein level), or a significantly large portion of such a protein which would retain some of the structural features of the protein, or such a protein which does not display any similarity at the sequence level, but has a similar (βα)₈ fold as AMPDA.

For human use, the compounds of the invention, and their pharmaceutically acceptable salts, can be administered alone but will generally be administered in admixture with a suitable pharmaceutical excipient, diluent or carrier selected with regard to the intended route of administration and standard pharmaceutical practice.

For example, the compounds, and their pharmaceutically acceptable salts, can be administered orally, buccally or sublingually in the form of tablets, capsules, ovules, elixirs, solutions or suspensions, which may contain flavouring or colouring agents, for immediate-, delayed-, modified-, sustained-, pulsed- or controlled-release applications.

The compounds can also be administered parenterally, for example, intravenously, intra-arterially, intraperitoneally, intrathecally, intraventricularly, intraurethrally, intrastemally, intracranially, intramuscularly or subcutaneously, or they may be administered by infusion or needleless injection techniques. For such parenteral administration they are best used in the form of a sterile aqueous solution which may contain other substances, for example, enough salts or glucose to make the solution isotonic with blood. The aqueous solutions should be suitably buffered (preferably to a pH of from 3 to 9), if necessary. The preparation of suitable parenteral formulations under sterile conditions is readily accomplished by standard pharmaceutical techniques well-known to those skilled in the art.

### EXAMPLES

The invention will now be illustrated by the following non-limiting examples and accompanying figures, in which:

SEQ ID NO: 1 illustrates the rabbit AMPDA cDNA sequence;

SEQ ID NO: 2 illustrates the rabbit AMPDA protein sequence;

SEQ ID NOs: 3-6 give the primer sequences used for amplification of the rabbit AMPDA coding sequence;

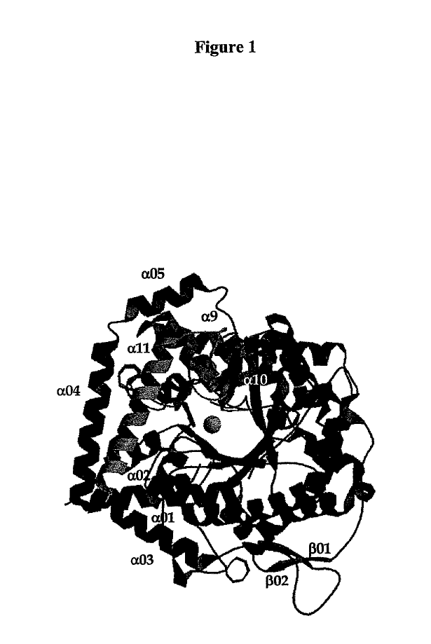

FIG. 1 illustrates the monomer structure of AMPDA; coloured by greyscale from the N-terminus to the C-terminus (dark to light). Helices and sheets additional to the core (βα)₈ barrel region are labelled. The zinc is depicted as a grey sphere.

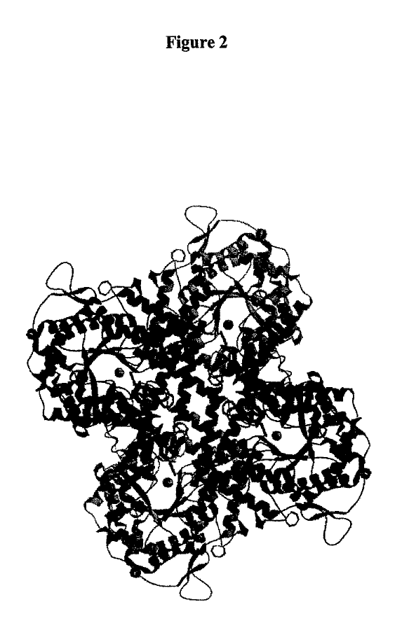

FIG. 2 illustrates the tetramer structure of AMPDA;

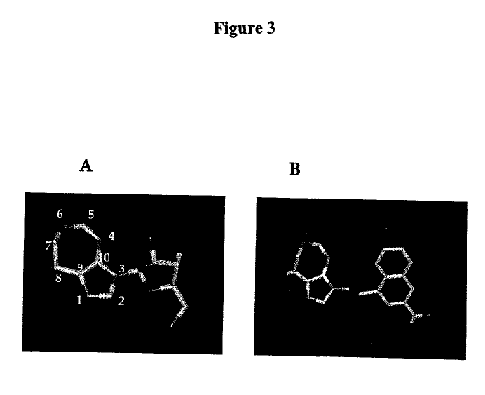

FIG. 3 shows the structures of coformycin (A) and UK-384,858 (B); atom positions are numbered for the seven membered ring system of coformycin;

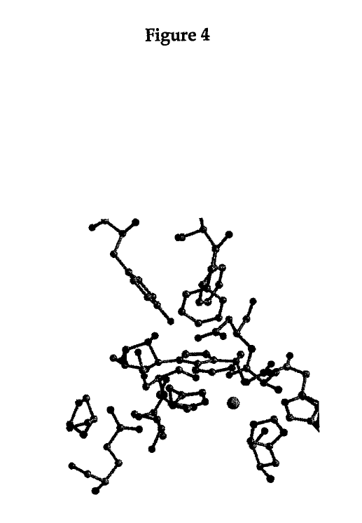

FIG. 4 shows the structure of the AMPDA-coformycin complex;

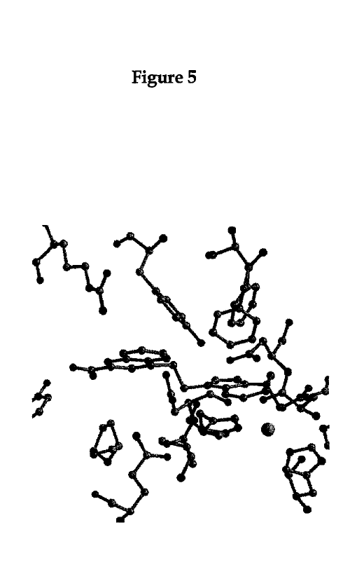

FIG. 5 shows the structure of the AMPDA-UK-384,858 complex; and

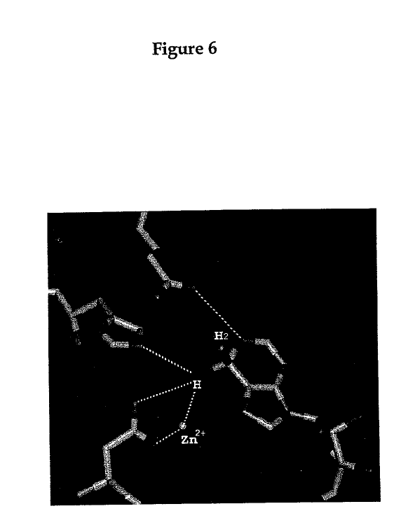

FIG. 6 shows the transition state model.

### Example 1

### Cloning of Rabbit AMPDA

A λgt10 rabbit chest muscle cDNA library was purchased (Clontech TL3000a) and used as the source of cDNA for the amplification of rabbit AMPDA by polymerase chain reaction (PCR). Four primers were designed using the human skeletal muscle AMPDA sequence (Sabina R. L. et al (1992) Neurology 42, 170-179); two of these primers, AMPDA1 and AMPDA2, were complementary to the 5′ and 3′ ends of the coding sequence of human AMPDA, respectively; primers AMPDA3 and AMPDA4 were internal primers, designed to enable the sequence to be amplified in two halves. Primers AMPDA1 and AMPDA4 were used to amplify the N-terminal portion, and AMPDA2 and AMPDA3 to amplify the C-terminal portion of the coding sequence:

| | |
|---|---|
| AMPDA-1 | |
| 5′-ATGCCTCTGTTCAAACTCCC-3′ | (SEQ ID NO: 3) |
| AMPDA-2 | |
| 5′-TTCTGTTGATTTAAGACCCTC-3′ | (SEQ ID NO: 4) |
| AMPDA-3 | |
| 5′-ATGAACCAGAAACATCTGCTG-3′ | (SEQ ID NO: 5) |
| AMPDA-4 | |
| 5′-CAGCAGATGTTTCTGGTTCATG-3′ | (SEQ ID NO: 6) |

Amplification was carried out using the above mentioned cDNA library as template, Taq polymerase (Life Technologies) and a MasterAmp™ PCR optimisation kit from Epicentre Technologies (Cambio). The amplification products were TA-cloned into pCRII (Invitrogen) as per manufacturer's protocol, and the DNA sequence determined by Lark Technologies (Saffron Walden, UK).

The rabbit cDNA sequence and the resulting translation product are shown in SEQ ID NOs: 1 and 2.

### Example 2

### Purification of Rabbit AMPDA

Purification of rabbit AMPDA was carried out following a procedure modified from Smiley, K. L., Berry, A. J. & Suelter, C. H. ((1967) J. Biol. Chem. 242, 2502-2506). Frozen rabbit muscle was obtained from Pel-Freez Biologicals Inc., Rogers, Arkansas. To one kilogram of thawed muscle was added 3 times its weight of extraction buffer composed of 0.18 M potassium chloride (KCl), 0.054 M potassium dihydrogen phosphate (KH₂PO₄), 0.035 M potassium hydrogen phosphate (K₂HPO₄) pH 6.50. After homogenisation for 30 seconds in a Waring blender, the homogenate was centrifuged at 14,000×g for 15 minutes, the resultant pellets being discarded. The supernatant fraction was decanted through synthetic cheese cloth to remove lipid particles prior to cellulose phosphate chromatography.

10 g of cellulose phosphate (Whatman) was prepared according to the manufacturer's instructions. The prepared cellulose phosphate was added directly to the supernatant fraction and stirred at room temperature. After one hour the cellulose phosphate was recovered by means of a sintered glass suction funnel, the filtrate being discarded. The cellulose phosphate was transferred to an XK 50/20 column and washed with 0.45 M potassium chloride, pH 7.0, 5 mM β-mercaptoethanol. When a stable UV absorbance was achieved, the column was eluted with 1.0 M KCl, pH 7.0, 5 mM β-mercaptoethanol. The eluted protein was stored at 4° C. for at least two weeks. During this period a mass loss of aproximately 10 kDa was observed from the N-terminus. The new N-terminus, determined by N-terminal sequencing and verified by mass spectroscopy, begins at Leu96, indicating that the N-terminal domain had been lost. This protein was then purified to homogeneity by means of gel filtration chromatography. A Superdex 200 HiLoad 26/60 column (Pharmacia) was equilibrated with 20 mM Tris-hydrochloride, pH 7.00, 10% glycerol, 200 mM sodium chloride, 5 mM β-mercaptoethanol. Several chromatography runs were performed, loading a maximum of 13 ml protein solution per run. Eluted fractions were analysed by 4-20% gradient sodium dodecyl sulphate polyacrylamide gel electrophoresis (SDS-PAGE). Those containing a single protein band, of molecular weight c. 70 kDa, were combined and concentrated.

### Example 3

### Crystallisation of Rabbit AMPDA

For crystallisation trials the purified protein was concentrated to 15 mg/ml using Ultra-free Tangental membranes (Millipore) with a molecular weight cut-off of 30 kDa. Crystallisation was performed, at 20° C., using the vapour-diffusion technique, with drops

TABLE 1
Crystallagraphic data and refinement statistics.

| | | Trimethyl | | Silver |
|---|---|---|---|---|
| Data Sets | | Lead Acetate | Xenon | Nitrate |
| (soaking conditions) | Native | 20 mM, 7 days | 8 bar, 7 minutes | 0.1 mM, 30 minutes |
| X-ray Source | Station 9.6, SRS | 1) Rotating anode | 1) Rotating anode | ID14-EH2, ESRF. |
| | | 2) Station 9.6, SRS | 2) Station 9.6, SRS | |
| Maximum | 2.2 | 1) 3.3, 2) 2.8 | 1) 3.0, 2) 2.2 | 2.5 |
| Resolution (Ø) | | | | |
| Phasing Power | | 1) 1.0/1.2 | 1) 2.6/1.7 | 1.0 |
| (ios/anom) | | 2) 2.0/1.0 | 1.6 | |

| Refinement Stats | native | Coformycin | UK-384, 858 |
|---|---|---|---|
| Resolution range | 30-2.2Ø | 30-2.5Ø | 3.0-2.2Ø |
| Observations | 1,079,312 | | |
| Uniques | 84,264 | | |
| Completeness | 99.9% | 96% | 97% |
| Rmerge* | 8.4% | 9% | 7% |

*Rmerge is as implemented by Otwinowski, Z & Minor, W. (1997) Methods Enzymol 276, 307-326.

containing 2 μl of protein and 2 μl of reservoir solution. A number of different crystal morphologies grew in similar conditions, the best diffracting crystal form, tetragonal rods, were obtained using 1.0 M citric acid (tri-sodium salt, dihydrate) as precipitant and 0.10 M imidazole, in the range pH 7.80-8.20, as buffer. The crystals belong to space group P4₂2₁2 with cell dimensions of a=148.7 Å, c=158.6 Å, and have a dimer in the asymmetric unit.

### Example 4

### Structure Solution

Native data, to 2.2 Å resolution, were collected at station 9.6 of the S.R.S. Daresbury, from crystals frozen at liquid nitrogen temperatures in a cryo-protecting solution comprising of mother liquor plus 20% glycerol. The structure was solved by multiple isomorphous replacement with anomalous scattering using three heavy atom derivatives. Table 1 details data collection and heavy atom statistics; the HKL package (Otwinowski, Z & Minor, W (1997) Methods Enzymol 276, 307-326), and the CCP4 (Acta Crystallogr D 50 (1994) 760-763) software suite were used for data processing and analysis. Heavy atom positions were derived from difference Patterson and difference Fourier calculations. The SHARP program (Fortelle E. d. -L. & Bricogne, G. (1997) Methods Enzymol 276, 472-494) was used to refine the heavy atom parameters and obtain initial phases, further heavy atom sites were identified from the residual map analysis available in SHARP. The maps were solvent flattened using SOLOMON (Abrahams, J. P. & Leslie, A. G. W. (1996) Acta Crystallogr. D52, 30-42) and 2-fold averaged with the DM program (Cowtan, K. (1994) Joint CCP4 and ESF-EACBM Newsletter on Protein Crystallography 31, 34-38).

The initial model of AMPDA was traced using the QUANTA package (Molecular Simulations Inc) and refined using all data to 2.2 Å with X-PLOR (Briinger, A. T. (1993) X-PLOR Version 3.1 A system for X-ray crystallography and NMR, Yale University Press, New Haven, Conn.). The torsion angle refinement procedure was used to escape initial local minima. Strict NCS constraints were applied through several cycles of model building and refinement. Individual B-factors were refined. The current model has a R_{cryst}=21.2% and a R_{free}=25.4%, calculated on 5% of the data set (Branger, A. T. (1992) Nature 355, 472-475).

The monomer structure can be described as follows. The catalytic domain of AMPDA is constructed around a core comprising the well precedented (βα)₈ barrel fold (Bränden, C. -I. (1991) Curr. Op. Struc. Biol. 1, 978-983). N-terminal to this barrel are five helices, a large loop and two short anti-parallel strands. These features wrap around the barrel forming an outer layer to the domain. Several additional secondary structural features are inserted between the secondary structural elements that comprise the barrel. Three helices are inserted in the loop between the first strand and helix of the barrel, and two short helices are inserted immediately after the barrel's third strand and third helix respectively. C-terminal to the (βα)₈ motif are three further helices, the first lies across the NH₂-terminal of the β-barrel, the second is short and packs anti-parallel to the first, while the third makes extensive contacts with the additional N-terminal helices. In total the enzyme contains 21 helices and 10 strands. By precedent the helices and strands of the (βα)₈-barrel are identified α1 through α8 and β1 through β8. The additional N-terminal helices and strands are labelled α01 through α05, β01 and β02 respectively. Helices inserted within the barrel-fold are termed α1′1 through α1′3, α3′ and α4′ to indicate their position in the fold, while the C-terminal helices are referred to as α9 through α11 (The nomenclature scheme is adapted from that of Wilson, D. K., Rudolph, F. B. & Quiocho, F. A. ((1991) Science 252, 1278-1284). A Zn²⁺ ion is bound at the C-terminus of the barrel at the bottom of a large cleft in the enzyme surface. The sides of this cleft are formed by the additional helices between the first and second strands of the barrel and the helix immediately following the third strand. This cleft contains the enzyme's active site. The structure is depicted in FIG. 1.

The Zn²⁺ co-ordination geometry best fits the trigonal bipyramid class (Alberts, I. L., Nadassy, K. & Wodak, S. J. (1998) Protein Science 7, 1700-1716), involving four residues, three histidines (His303, 305 and 572) and Asp649. The remaining co-ordination site can be accounted for as a discrete density peak about 1.8 Å from the Zn²⁺ was observed throughout refinement and was modelled as the activated water molecule required for catalysis.

Four disordered regions have not been modelled in the apo-structure. Density is not observed for the N-terminal 10 residues, a six residue loop immediately prior to the first helix cannot be modelled, 11 residues forming a loop close to the active site are disordered and the two C-terminal residues are absent.

A tetramer is observed in the crystals (FIG. 2). Two sub-units are packed around a non-crystallographic diad axis forming the asymmetric unit. This dimer is packed around the crystallographic 2-fold axis in z to give the physiologically observed tetramer. An extensive buried surface indicates that the tetramer is tightly associated, and inter-subunit contacts are made almost exclusively by the helices additional to the (βα)₈ barrel.

The atomic coordinates are given in Table 2.

### Example 5

### Soaking of AMPDA with Inhibitors and Structure Solution of Enzyme-Inhibitor Complexes

The coformycin and UK-384,858 enzyme inhibitor complexes were prepared by soaking the crystals in a solution corresponding to the well solution plus 10 mM inhibitor. The crystals were shown to tolerate DMSO concentrations of 10% and higher, allowing inhibitors with a relatively low solubility, such as UK-384,858, to be used. Data were collected as described above, the inhibitor structures were modelled into initial difference maps, using the QUANTA software, and have been refined in X-PLOR to give R_{cryst}=20.7% (R_{free}=26.1% ), and R_{cryst}=22.9% (R_{free}=25.8%) respectively. All three structures presented have good stereochemistry as judged by the PROCHECK program (Laskowski, R. A. et al (1993) J. Appl. Crystallogr. 26, 283-291). Figures were prepared using the software packages MOLSCRIPT (Kraulis, P. J. (1991) J. Appl. Crystallogr. 24, 946-950) and RASTER3D (Merrit, E. A. & Murphy, M. E. P. (1994) Acta Crystallogr. D50, 869-873).

a) The complex with Coformycin

The structure of the enzyme complexed with coformycin (the structure of which is shown in FIG. 3) at 2.5 Å resolution shows the inhibitor bound at the base of the active site cleft. The seven-membered ring binds in a pocket which can accommodate the substrate's adenosine group. The 8-hydroxyl displaces the activated water seen in the apo-structure and hydrogen bonds the Zn²⁺. The hydroxyl to Zn²⁺ distance is 1.8 Å. The tetrahedral geometry observed at the C8 position is consistent with coformycin being a transition-state analogue inhibitor of the enzyme. The 11 residues (366-377), disordered in the apostructure, pack against the bicyclic ring system forming a loop and short (three turn) helix motif, termed the 370 helix. The 370 helix is amphipathic and the hydrophobic face contains two phenylalanine residues (Phe372 and Phe375) which pack against the inhibitor entirely enclosing this portion of the binding site from solvent. The stacking interactions made between the inhibitor ring system and these aromatic residues stabilise the disordered loop. Key inhibitor recognition features include two hydrogen bonds made by acidic residues in the binding site. Asp650 forms a hydrogen bond with N1 of coformycin (D650 Oδ1-N1, 2.3 Å) and is co-planar with the ring, while Glu575 is 2.9 Å from N6 and has good geometry to accept a proton. The main chain amide group of Asp513 is positioned to act as a hydrogen bond donating group with the N4 atom of the inhibitor as the acceptor, the distance between these two atoms is however too large (4.4 Å) for a good hydrogen bond to be made. Additional residues involved in van der Waals interactions in the purine binding pocket include the Zn²⁺ co-ordinating residues His305 and His594. The bicyclic ring system of the inhibitor packs against the plane of these histidine residues and is essentially sandwiched between these aromatic side chains and the two ordered phenylalanine residues of the 370 helix (FIG. 4).

The ribose binding site is less tightly defined. Two hydrogen bonds are made by hydroxyl groups, the 2′-OH is 3.0 Å from Asn376 Nδ2 and the 5′-OH group is 3.2 Å from Gln458 Nδ1. The orientation of Gln458 is fixed in a position to form this hydrogen bond by a hydrogen bonding network through His305 to the catalytic zinc. van der Waals interactions are made by the ribose ring to four hydrophobic side-chains, namely Pro460, Val512, Phe375 and Tyr379 (FIG. 4). The location of the phosphate binding site can be predicted from the structure of the complex with coformycin, the basic residues Lys393 and Arg388 are ideally positioned to co-ordinate a phosphate group as are the main-chain NH groups of the flexible loop of alanine residues 306-308.

The atomic coordinates are shown in Table 3.

b) The Complex with UK-384,858

A number of AMPDA specific inhibitors, based around coformycin, have been reported (Erion, M. D. et al (1999) J. Am. Chem. Soc. 121, 308-319; Bookser, B. C. et al. (2000) J. Med. Chem. 43, 1495-1507). UK-384,858 (FIG. 3) is a potent of example of these inhibitors in which the ribose unit of coformycin has been replaced by an ethyl linked naphthalene group with a carbocylic acid substitutent. The crystal structure of the enzyme inhibitor complex has been solved and refined at 2.2 Å resolution. The complex is consistent with that observed with coformycin; the ordering of the active site, tetrahedral transition state geometry binding of the Zn²⁺, and all previously described interactions in the purine binding site are observed. The naphthalene group is seen to pack in a highly hydrophobic environment making van der Waals interactions with residues Pro460, Ile462, Phe372 and the Cα atom of Asp513. The ethyl linker group is also involved in hydrophobic contacts with Phe375. The acidic group is shown to be within hydrogen bonding distance of Tyr429, Ser427 and Arg388 (FIG. 5).

The atomic coordinates for this structure are shown in Table 4.

### Example 6

### Homology with Adenosine Deaminase: Mechanism Conservation

Despite having diverse sequences, AMPDA shares a conserved catalytic mechanism with adenosine deaminase (ADA). ADA is a monomeric, 40 kDalton, protein which catalyses the hydrolysis of adenosine to inosine (Wilson, D. K., Rudolph, F. B. & Quiocho, F. A. (1991) Science 252, 1278-1284). In common with AMPDA, ADA co-ordinates a catalytic zinc atom within a (βα)₈ barrel. The inserted loop, containing 3 helices, between the first stand and helix of the barrel is common to both enzymes and forms part of a highly conserved purine binding site (Sharff, A. J. et al (1992) J. Mol. Biol. 226, 917-921).

The mechanism of ADA has been examined extensively by a combination of crystallographic (Wang, Z. & Quiocho, F. A. (1998) Biochemistry 37, 8314-8324) and site-directed mutagenesis studies (Sideraki, V. et al (1996) Biochemistry 35, 15019-15028). All the residues identified as being important for the mechanism of ADA are equivalent in AMPDA and it is clear that the mechanism has been conserved in evolution. The reaction has been described in two stages: an initial stereo-specific hydroxide addition to form a tetrahedral (at the substrate C6 position) transition-state intermediate, and a final ammonia elimination to form the inosine product. The Zn²⁺ acts as a powerful electrophile, as demonstrated by the presence of the hydroxide ion (activated water) in the apo-AMPDA structure and the analogous observation reported in an ADA inhibitor complex structure (Wilson, D. K. & Quiocho, F. A. (1993) Biochemistry 32, 1689-1694). The transition state is stabilised by the Glu575—substrate N6 interaction. His238 in ADA, which is equivalent to His594 in AMPDA, has been shown to promote hydroxide formation, while Asp649 is positioned to orientate the hydroxide oxygen in line for addition to C6 (FIG. 6). The position of the Zn²⁺ ion and Asp649 dictate the pro-S stereo-specificity of the reaction.

The second stage, the elimination of ammonia, is less well understood. Two pathways have been postulated, either Asp649 or Glu575 acts as the shuttle for the proton from the 6-OH to the 6-NH₂ of the tetrahedral intermediate (Wilson, D. K. & Quiocho, F. A. (1993) Biochemistry 32, 1689-1694).

### Example 7

### Assay for AMPDA Activity

There are many assays for AMPDA activity in the prior art (e.g. as in Smiley, K. L., Berry, A. J. & Suelter, C. H. (1967) J. Biol. Chem. 242, 2502-2506). Typically, the assay was performed in microtitre plates. To each well, 10 μl of test compound, diluted in sodium citrate buffer (10 mM, pH 6.5) with 10% DMSO and 70 μl of sodium citrate buffer were added; the plate was mixed with a plate shaker. Then 10 μl of enzyme stock solution in 1M KCl were added, and the plate was mixed again, and incubated for 5 minutes. This was followed by the addition of 10 μl substrate solution (10 mM 5′-AMP in sodium citrate buffer). After mixing and 5 minutes incubation, 150 μl of Ninhydrin reagent (Sigmna, N1632) were added to each well to stop the reaction. The plate was then covered and left overnight for the colour to develop. The absorbance at 570 nm was measured with an appropriate standard plate reader (e.g. Molecular Devices Spectramax Plus).

TABLE 2
Atomic coordinates for native AMPDA

| | |
|---|---|
| REMARK | xplor input |
| CRYST1 | 148.662 148.662 158.563 90.00 90.00 90.00 P42212 |

| | |
|---|---|
| SCALE1 | 0.00673 0.00000 0.00000 0.00000 |
| SCALE2 | 0.00000 0.00673 0.00000 0.00000 |
| SCALE3 | 0.00000 0.00000 0.00631 0.00000 |

REMARK FILENAME = “brefinement2.pdb”
REMARK r = 0.217303 free_r = 0.253691
REMARK DATE: 07-Apr-00 09:55:33 created by user: chrisp

| | | | | | | | | | | | | |
|---|---|---|---|---|---|---|---|---|---|---|---|---|
| ATOM | 1 | CB | SER | A | 106 | 17.660 | 72.293 | 93.304 | 1.00 | 36.73 | A | C |
| ATOM | 2 | OG | SER | A | 106 | 18.932 | 72.331 | 92.673 | 1.00 | 39.63 | A | O |
| ATOM | 3 | C | SER | A | 106 | 18.780 | 74.233 | 94.425 | 1.00 | 37.36 | A | C |
| ATOM | 4 | O | SER | A | 106 | 18.616 | 75.314 | 93.843 | 1.00 | 39.40 | A | O |
| ATOM | 5 | N | SER | A | 106 | 16.286 | 73.863 | 94.664 | 1.00 | 35.79 | A | N |
| ATOM | 6 | CA | SER | A | 106 | 17.632 | 73.212 | 94.528 | 1.00 | 38.08 | A | C |
| ATOM | 7 | N | PRO | A | 107 | 19.969 | 73.879 | 94.961 | 1.00 | 34.45 | A | N |
| ATOM | 8 | CD | PRO | A | 107 | 20.279 | 72.578 | 95.575 | 1.00 | 31.68 | A | C |
| ATOM | 9 | CA | PRO | A | 107 | 21.144 | 74.757 | 94.942 | 1.00 | 32.61 | A | C |
| ATOM | 10 | CB | PRO | A | 107 | 22.240 | 73.916 | 95.589 | 1.00 | 29.27 | A | C |
| ATOM | 11 | CG | PRO | A | 107 | 21.536 | 72.853 | 96.322 | 1.00 | 30.06 | A | C |
| ATOM | 12 | C | PRO | A | 107 | 21.555 | 75.222 | 93.544 | 1.00 | 36.30 | A | C |
| ATOM | 13 | O | PRO | A | 107 | 21.972 | 76.370 | 93.363 | 1.00 | 36.38 | A | O |
| ATOM | 14 | N | THR | A | 108 | 21.433 | 74.335 | 92.557 | 1.00 | 36.49 | A | N |
| ATOM | 15 | CA | THR | A | 108 | 21.819 | 74.658 | 91.182 | 1.00 | 36.24 | A | C |
| ATOM | 16 | CB | THR | A | 108 | 21.773 | 73.396 | 90.284 | 1.00 | 35.59 | A | C |
| ATOM | 17 | OG1 | THR | A | 108 | 20.411 | 73.069 | 89.988 | 1.00 | 40.24 | A | O |
| ATOM | 18 | CG2 | THR | A | 108 | 22.431 | 72.211 | 90.988 | 1.00 | 34.71 | A | C |
| ATOM | 19 | C | THR | A | 108 | 21.019 | 75.776 | 90.497 | 1.00 | 34.95 | A | C |
| ATOM | 20 | O | THR | A | 108 | 21.460 | 76.312 | 89.478 | 1.00 | 38.35 | A | O |
| ATOM | 21 | N | TYR | A | 109 | 19.861 | 76.144 | 91.043 | 1.00 | 33.44 | A | N |
| ATOM | 22 | CA | TYR | A | 109 | 19.063 | 77.196 | 90.423 | 1.00 | 30.09 | A | C |
| ATOM | 23 | CB | TYR | A | 109 | 17.578 | 76.919 | 90.632 | 1.00 | 30.13 | A | C |
| ATOM | 24 | CG | TYR | A | 109 | 17.004 | 76.001 | 89.574 | 1.00 | 32.99 | A | C |
| ATOM | 25 | CD1 | TYR | A | 109 | 17.628 | 74.785 | 89.266 | 1.00 | 32.21 | A | C |
| ATOM | 26 | CE1 | TYR | A | 109 | 17.095 | 73.914 | 88.302 | 1.00 | 31.44 | A | C |
| ATOM | 27 | CD2 | TYR | A | 109 | 15.830 | 76.333 | 88.887 | 1.00 | 31.39 | A | C |
| ATOM | 28 | CE2 | TYR | A | 109 | 15.287 | 75.471 | 87.921 | 1.00 | 30.63 | A | C |
| ATOM | 29 | CZ | TYR | A | 109 | 15.925 | 74.262 | 87.637 | 1.00 | 30.96 | A | C |
| ATOM | 30 | OH | TYR | A | 109 | 15.385 | 73.396 | 86.709 | 1.00 | 30.15 | A | O |
| ATOM | 31 | C | TYR | A | 109 | 19.405 | 78.594 | 90.920 | 1.00 | 28.39 | A | C |
| ATOM | 32 | O | TYR | A | 109 | 18.695 | 79.553 | 90.626 | 1.00 | 26.10 | A | O |
| ATOM | 33 | N | GLN | A | 110 | 20.502 | 78.713 | 91.661 | 1.00 | 26.96 | A | N |
| ATOM | 34 | CA | GLN | A | 110 | 20.913 | 80.011 | 92.190 | 1.00 | 28.12 | A | C |
| ATOM | 35 | CB | GLN | A | 110 | 22.230 | 79.876 | 92.976 | 1.00 | 30.05 | A | C |
| ATOM | 36 | CG | GLN | A | 110 | 22.643 | 81.138 | 93.763 | 1.00 | 31.07 | A | C |
| ATOM | 37 | CD | GLN | A | 110 | 21.683 | 81.470 | 94.912 | 1.00 | 32.52 | A | C |
| ATOM | 38 | OE1 | GLN | A | 110 | 20.785 | 80.681 | 95.238 | 1.00 | 34.45 | A | O |
| ATOM | 39 | NE2 | GLN | A | 110 | 21.871 | 82.639 | 95.528 | 1.00 | 28.58 | A | N |
| ATOM | 40 | C | GLN | A | 110 | 21.130 | 80.974 | 91.037 | 1.00 | 28.33 | A | C |
| ATOM | 41 | O | GLN | A | 110 | 21.056 | 82.193 | 91.186 | 1.00 | 26.06 | A | O |
| ATOM | 42 | N | THR | A | 111 | 21.372 | 80.386 | 89.873 | 1.00 | 27.56 | A | N |
| ATOM | 43 | CA | THR | A | 111 | 21.678 | 81.102 | 88.659 | 1.00 | 23.00 | A | C |
| ATOM | 44 | CB | THR | A | 111 | 22.874 | 80.373 | 88.022 | 1.00 | 25.72 | A | C |
| ATOM | 45 | OG1 | THR | A | 111 | 23.994 | 81.253 | 87.999 | 1.00 | 30.39 | A | O |
| ATOM | 46 | CG2 | THR | A | 111 | 22.570 | 79.878 | 86.661 | 1.00 | 22.63 | A | C |
| ATOM | 47 | C | THR | A | 111 | 20.509 | 81.239 | 87.682 | 1.00 | 23.00 | A | C |
| ATOM | 48 | O | THR | A | 111 | 20.606 | 81.952 | 86.679 | 1.00 | 21.80 | A | O |
| ATOM | 49 | N | VAL | A | 112 | 19.396 | 80.579 | 87.995 | 1.00 | 19.03 | A | N |
| ATOM | 50 | CA | VAL | A | 112 | 18.216 | 80.586 | 87.136 | 1.00 | 17.22 | A | C |
| ATOM | 51 | CB | VAL | A | 112 | 17.575 | 79.196 | 87.128 | 1.00 | 15.07 | A | C |
| ATOM | 52 | CG1 | VAL | A | 112 | 16.369 | 79.178 | 86.208 | 1.00 | 12.58 | A | C |
| ATOM | 53 | CG2 | VAL | A | 112 | 18.619 | 78.154 | 86.719 | 1.00 | 12.59 | A | C |
| ATOM | 54 | C | VAL | A | 112 | 17.135 | 81.596 | 87.510 | 1.00 | 17.71 | A | C |
| ATOM | 55 | O | VAL | A | 112 | 16.541 | 81.485 | 88.572 | 1.00 | 18.11 | A | O |
| ATOM | 56 | N | PRO | A | 113 | 16.854 | 82.582 | 86.627 | 1.00 | 16.70 | A | N |
| ATOM | 57 | CD | PRO | A | 113 | 17.480 | 82.811 | 85.315 | 1.00 | 13.13 | A | C |
| ATOM | 58 | CA | PRO | A | 113 | 15.820 | 83.585 | 86.920 | 1.00 | 15.12 | A | C |
| ATOM | 59 | CB | PRO | A | 113 | 15.863 | 84.525 | 85.721 | 1.00 | 14.74 | A | C |
| ATOM | 60 | CG | PRO | A | 113 | 17.144 | 84.229 | 85.025 | 1.00 | 13.40 | A | C |
| ATOM | 61 | C | PRO | A | 113 | 14.453 | 82.930 | 87.041 | 1.00 | 16.90 | A | C |
| ATOM | 62 | O | PRO | A | 113 | 14.263 | 81.780 | 86.635 | 1.00 | 16.26 | A | O |
| ATOM | 63 | N | ASP | A | 114 | 13.501 | 83.652 | 87.615 | 1.00 | 17.91 | A | N |
| ATOM | 64 | CA | ASP | A | 114 | 12.157 | 83.114 | 87.737 | 1.00 | 19.86 | A | C |
| ATOM | 65 | CB | ASP | A | 114 | 11.300 | 83.996 | 88.656 | 1.00 | 25.19 | A | C |
| ATOM | 66 | CG | ASP | A | 114 | 11.690 | 83.884 | 90.126 | 1.00 | 32.77 | A | C |
| ATOM | 67 | OD1 | ASP | A | 114 | 12.242 | 82.836 | 90.537 | 1.00 | 37.08 | A | O |
| ATOM | 68 | OD2 | ASP | A | 114 | 11.436 | 84.855 | 90.877 | 1.00 | 37.82 | A | O |
| ATOM | 69 | C | ASP | A | 114 | 11.547 | 83.145 | 86.330 | 1.00 | 18.50 | A | C |
| ATOM | 70 | O | ASP | A | 114 | 12.011 | 83.886 | 85.457 | 1.00 | 18.75 | A | O |
| ATOM | 71 | N | PHE | A | 115 | 10.526 | 82.331 | 86.111 | 1.00 | 14.13 | A | N |
| ATOM | 72 | CA | PHE | A | 115 | 9.810 | 82.320 | 84.849 | 1.00 | 13.56 | A | C |
| ATOM | 73 | CB | PHE | A | 115 | 10.681 | 81.775 | 83.691 | 1.00 | 13.44 | A | C |
| ATOM | 74 | CG | PHE | A | 115 | 11.061 | 80.320 | 83.802 | 1.00 | 11.10 | A | C |
| ATOM | 75 | CD1 | PHE | A | 115 | 12.246 | 79.946 | 84.426 | 1.00 | 11.56 | A | C |
| ATOM | 76 | CD2 | PHE | A | 115 | 10.274 | 79.333 | 83.220 | 1.00 | 12.79 | A | C |
| ATOM | 77 | CE1 | PHE | A | 115 | 12.645 | 78.613 | 84.470 | 1.00 | 11.59 | A | C |
| ATOM | 78 | CE2 | PHE | A | 115 | 10.671 | 77.977 | 83.257 | 1.00 | 14.84 | A | C |
| ATOM | 79 | CZ | PHE | A | 115 | 11.862 | 77.625 | 83.887 | 1.00 | 12.71 | A | C |
| ATOM | 80 | C | PHE | A | 115 | 8.526 | 81.535 | 85.037 | 1.00 | 12.44 | A | C |
| ATOM | 81 | O | PHE | A | 115 | 8.427 | 80.734 | 85.962 | 1.00 | 15.08 | A | O |
| ATOM | 82 | N | GLN | A | 116 | 7.526 | 81.798 | 84.203 | 1.00 | 10.82 | A | N |
| ATOM | 83 | CA | GLN | A | 116 | 6.259 | 81.096 | 84.318 | 1.00 | 12.72 | A | C |
| ATOM | 84 | CB | GLN | A | 116 | 5.171 | 81.865 | 83.589 | 1.00 | 12.76 | A | C |
| ATOM | 85 | CG | GLN | A | 116 | 5.117 | 83.312 | 83.999 | 1.00 | 17.63 | A | C |
| ATOM | 86 | CD | GLN | A | 116 | 3.890 | 84.007 | 83.463 | 1.00 | 20.43 | A | C |
| ATOM | 87 | OE1 | GLN | A | 116 | 3.959 | 84.679 | 82.448 | 1.00 | 22.40 | A | O |
| ATOM | 88 | NE2 | GLN | A | 116 | 2.754 | 83.840 | 84.140 | 1.00 | 23.33 | A | N |
| ATOM | 89 | C | GLN | A | 116 | 6.345 | 79.682 | 83.770 | 1.00 | 13.02 | A | C |
| ATOM | 90 | O | GLN | A | 116 | 6.800 | 79.452 | 82.654 | 1.00 | 14.41 | A | O |
| ATOM | 91 | N | ARG | A | 117 | 5.893 | 78.727 | 84.561 | 1.00 | 14.81 | A | N |
| ATOM | 92 | CA | ARG | A | 117 | 5.940 | 77.345 | 84.140 | 1.00 | 14.81 | A | C |
| ATOM | 93 | CB | ARG | A | 117 | 6.579 | 76.506 | 85.230 | 1.00 | 14.79 | A | C |
| ATOM | 94 | CG | ARG | A | 117 | 8.076 | 76.534 | 85.162 | 1.00 | 19.17 | A | C |
| ATOM | 95 | CD | ARG | A | 117 | 8.618 | 76.773 | 86.522 | 1.00 | 22.56 | A | C |
| ATOM | 96 | NE | ARG | A | 117 | 10.022 | 76.402 | 86.625 | 1.00 | 21.56 | A | N |
| ATOM | 97 | CZ | ARG | A | 117 | 10.951 | 77.214 | 87.107 | 1.00 | 20.65 | A | C |
| ATOM | 98 | NH1 | ARG | A | 117 | 10.603 | 78.428 | 87.518 | 1.00 | 21.34 | A | N |
| ATOM | 99 | NH2 | ARG | A | 117 | 12.213 | 76.811 | 87.194 | 1.00 | 17.04 | A | N |
| ATOM | 100 | C | ARG | A | 117 | 4.564 | 76.827 | 83.852 | 1.00 | 14.88 | A | C |
| ATOM | 101 | O | ARG | A | 117 | 3.571 | 77.346 | 84.367 | 1.00 | 18.01 | A | O |
| ATOM | 102 | N | VAL | A | 118 | 4.482 | 75.805 | 83.021 | 1.00 | 14.84 | A | N |
| ATOM | 103 | CA | VAL | A | 118 | 3.176 | 75.252 | 82.763 | 1.00 | 17.65 | A | C |
| ATOM | 104 | CB | VAL | A | 118 | 2.877 | 75.064 | 81.215 | 1.00 | 19.65 | A | C |
| ATOM | 105 | CG1 | VAL | A | 118 | 4.021 | 75.641 | 80.367 | 1.00 | 18.38 | A | C |
| ATOM | 106 | CG2 | VAL | A | 118 | 2.589 | 73.597 | 80.889 | 1.00 | 18.29 | A | C |
| ATOM | 107 | C | VAL | A | 118 | 3.137 | 73.947 | 83.520 | 1.00 | 16.98 | A | C |
| ATOM | 108 | O | VAL | A | 118 | 4.012 | 73.099 | 83.375 | 1.00 | 19.34 | A | O |
| ATOM | 109 | N | GLN | A | 119 | 2.144 | 73.806 | 84.383 | 1.00 | 19.99 | A | N |
| ATOM | 110 | CA | GLN | A | 119 | 2.022 | 72.566 | 85.120 | 1.00 | 22.25 | A | C |
| ATOM | 111 | CB | GLN | A | 119 | 2.380 | 72.772 | 86.584 | 1.00 | 24.57 | A | C |
| ATOM | 112 | CG | GLN | A | 119 | 1.628 | 73.874 | 87.255 | 1.00 | 34.50 | A | C |
| ATOM | 113 | CD | GLN | A | 119 | 1.860 | 73.864 | 88.755 | 1.00 | 42.66 | A | C |
| ATOM | 114 | OE1 | GLN | A | 119 | 0.939 | 73.607 | 89.540 | 1.00 | 44.02 | A | O |
| ATOM | 115 | NE2 | GLN | A | 119 | 3.101 | 74.133 | 89.162 | 1.00 | 41.01 | A | N |
| ATOM | 116 | C | GLN | A | 119 | 0.631 | 71.982 | 84.970 | 1.00 | 18.77 | A | C |
| ATOM | 117 | O | GLN | A | 119 | −0.360 | 72.699 | 84.859 | 1.00 | 19.15 | A | O |
| ATOM | 118 | N | ILE | A | 120 | 0.585 | 70.660 | 84.957 | 1.00 | 17.36 | A | N |
| ATOM | 119 | CA | ILE | A | 120 | −0.642 | 69.936 | 84.775 | 1.00 | 17.71 | A | C |
| ATOM | 120 | CB | ILE | A | 120 | −0.434 | 68.791 | 83.740 | 1.00 | 14.99 | A | C |
| ATOM | 121 | CG2 | ILE | A | 120 | −1.745 | 68.078 | 83.469 | 1.00 | 11.38 | A | C |
| ATOM | 122 | CG1 | ILE | A | 120 | 0.207 | 69.354 | 82.466 | 1.00 | 12.22 | A | C |
| ATOM | 123 | CD1 | ILE | A | 120 | −0.488 | 70.558 | 81.858 | 1.00 | 11.20 | A | C |
| ATOM | 124 | C | ILE | A | 120 | −1.095 | 69.351 | 86.099 | 1.00 | 19.36 | A | C |
| ATOM | 125 | O | ILE | A | 120 | −0.355 | 68.632 | 86.753 | 1.00 | 17.41 | A | O |
| ATOM | 126 | N | THR | A | 121 | −2.324 | 69.659 | 86.485 | 1.00 | 20.51 | A | N |
| ATOM | 127 | CA | THR | A | 121 | −2.881 | 69.136 | 87.719 | 1.00 | 23.82 | A | C |
| ATOM | 128 | CB | THR | A | 121 | −3.870 | 70.119 | 88.337 | 1.00 | 21.31 | A | C |
| ATOM | 129 | OG1 | THR | A | 121 | −5.124 | 69.979 | 87.675 | 1.00 | 25.83 | A | O |
| ATOM | 130 | CG2 | THR | A | 121 | −3.398 | 71.536 | 88.188 | 1.00 | 21.53 | A | C |
| ATOM | 131 | C | THR | A | 121 | −3.641 | 67.852 | 87.405 | 1.00 | 27.24 | A | C |
| ATOM | 132 | O | THR | A | 121 | −3.999 | 67.605 | 86.261 | 1.00 | 31.10 | A | O |
| ATOM | 133 | N | GLY | A | 122 | −3.882 | 67.030 | 88.419 | 1.00 | 30.42 | A | N |
| ATOM | 134 | CA | GLY | A | 122 | −4.632 | 65.803 | 88.198 | 1.00 | 35.25 | A | C |
| ATOM | 135 | C | GLY | A | 122 | −3.818 | 64.553 | 87.925 | 1.00 | 39.16 | A | C |
| ATOM | 136 | O | GLY | A | 122 | −2.614 | 64.621 | 87.638 | 1.00 | 39.38 | A | O |
| ATOM | 137 | N | ASP | A | 123 | −4.494 | 63.406 | 88.008 | 1.00 | 41.48 | A | N |
| ATOM | 138 | CA | ASP | A | 123 | −3.874 | 62.102 | 87.787 | 1.00 | 44.93 | A | C |
| ATOM | 139 | CB | ASP | A | 123 | −4.684 | 60.999 | 88.481 | 1.00 | 50.08 | A | C |
| ATOM | 140 | CG | ASP | A | 123 | −5.004 | 61.327 | 89.933 | 1.00 | 55.60 | A | C |
| ATOM | 141 | OD1 | ASP | A | 123 | −4.060 | 61.631 | 90.700 | 1.00 | 58.56 | A | O |
| ATOM | 142 | OD2 | ASP | A | 123 | −6.200 | 61.277 | 90.307 | 1.00 | 59.98 | A | O |
| ATOM | 143 | C | ASP | A | 123 | −3.785 | 61.778 | 86.310 | 1.00 | 44.98 | A | C |
| ATOM | 144 | O | ASP | A | 123 | −4.733 | 62.012 | 85.558 | 1.00 | 46.21 | A | O |
| ATOM | 145 | N | TYR | A | 124 | −2.656 | 61.218 | 85.895 | 1.00 | 44.90 | A | N |
| ATOM | 146 | CA | TYR | A | 124 | −2.476 | 60.861 | 84.493 | 1.00 | 46.23 | A | C |
| ATOM | 147 | CB | TYR | A | 124 | −0.985 | 60.739 | 84.180 | 1.00 | 43.26 | A | C |
| ATOM | 148 | CG | TYR | A | 124 | −0.388 | 62.055 | 83.768 | 1.00 | 37.95 | A | C |
| ATOM | 149 | CD1 | TYR | A | 124 | 0.302 | 62.836 | 84.687 | 1.00 | 35.00 | A | C |
| ATOM | 150 | CE1 | TYR | A | 124 | 0.793 | 64.090 | 84.339 | 1.00 | 35.93 | A | C |
| ATOM | 151 | CD2 | TYR | A | 124 | −0.572 | 62.552 | 82.481 | 1.00 | 34.94 | A | C |
| ATOM | 152 | CE2 | TYR | A | 124 | −0.083 | 63.807 | 82.123 | 1.00 | 36.99 | A | C |
| ATOM | 153 | CZ | TYR | A | 124 | 0.598 | 64.573 | 83.061 | 1.00 | 32.61 | A | C |
| ATOM | 154 | OH | TYR | A | 124 | 1.071 | 65.819 | 82.730 | 1.00 | 30.82 | A | O |
| ATOM | 155 | C | TYR | A | 124 | −3.204 | 59.564 | 84.117 | 1.00 | 48.00 | A | C |
| ATOM | 156 | O | TYR | A | 124 | −2.781 | 58.487 | 84.608 | 1.00 | 50.21 | A | O |
| ATOM | 157 | OT | TYR | A | 124 | −4.190 | 59.643 | 83.341 | 1.00 | 47.96 | A | O |
| ATOM | 158 | CB | ASP | B | 132 | −2.925 | 48.884 | 79.818 | 1.00 | 50.62 | B | C |
| ATOM | 159 | CG | ASP | B | 132 | −3.086 | 49.237 | 78.337 | 1.00 | 56.63 | B | C |
| ATOM | 160 | OD1 | ASP | B | 132 | −3.417 | 50.410 | 78.033 | 1.00 | 57.78 | B | O |
| ATOM | 161 | OD2 | ASP | B | 132 | −2.881 | 48.344 | 77.478 | 1.00 | 58.24 | B | O |
| ATOM | 162 | C | ASP | B | 132 | −0.464 | 49.378 | 79.977 | 1.00 | 42.53 | B | C |
| ATOM | 163 | O | ASP | B | 132 | 0.435 | 49.247 | 79.145 | 1.00 | 40.42 | B | O |
| ATOM | 164 | N | ASP | B | 132 | −1.527 | 47.726 | 81.524 | 1.00 | 43.34 | B | N |
| ATOM | 165 | CA | ASP | B | 132 | −1.538 | 48.299 | 80.141 | 1.00 | 45.78 | B | C |
| ATOM | 166 | N | PHE | B | 133 | −0.576 | 50.453 | 80.753 | 1.00 | 41.07 | B | N |
| ATOM | 167 | CA | PHE | B | 133 | 0.413 | 51.526 | 80.703 | 1.00 | 40.85 | B | C |
| ATOM | 168 | CB | PHE | B | 133 | 0.030 | 52.686 | 81.639 | 1.00 | 38.88 | B | C |
| ATOM | 169 | CG | PHE | B | 133 | 1.081 | 53.777 | 81.724 | 1.00 | 40.37 | B | C |
| ATOM | 170 | CD1 | PHE | B | 133 | 1.302 | 54.460 | 82.919 | 1.00 | 36.29 | B | C |
| ATOM | 171 | CD2 | PHE | B | 133 | 1.854 | 54.123 | 80.597 | 1.00 | 40.45 | B | C |
| ATOM | 172 | CE1 | PHE | B | 133 | 2.273 | 55.470 | 82.991 | 1.00 | 37.05 | B | C |
| ATOM | 173 | CE2 | PHE | B | 133 | 2.830 | 55.134 | 80.660 | 1.00 | 35.98 | B | C |
| ATOM | 174 | CZ | PHE | B | 133 | 3.038 | 55.805 | 81.854 | 1.00 | 36.72 | B | C |
| ATOM | 175 | C | PHE | B | 133 | 1.671 | 50.865 | 81.224 | 1.00 | 41.21 | B | C |
| ATOM | 176 | O | PHE | B | 133 | 2.792 | 51.199 | 80.844 | 1.00 | 42.36 | B | O |
| ATOM | 177 | N | GLU | B | 134 | 1.445 | 49.907 | 82.109 | 1.00 | 40.24 | B | N |
| ATOM | 178 | CA | GLU | B | 134 | 2.500 | 49.145 | 82.733 | 1.00 | 39.62 | B | C |
| ATOM | 179 | CB | GLU | B | 134 | 1.878 | 48.038 | 83.572 | 1.00 | 45.49 | B | C |
| ATOM | 180 | CG | GLU | B | 134 | 2.422 | 47.956 | 84.979 | 1.00 | 52.21 | B | C |
| ATOM | 181 | CD | GLU | B | 134 | 3.184 | 46.668 | 85.225 | 1.00 | 57.35 | B | C |
| ATOM | 182 | OE1 | GLU | B | 134 | 2.809 | 45.624 | 84.632 | 1.00 | 59.46 | B | O |
| ATOM | 183 | OE2 | GLU | B | 134 | 4.159 | 46.705 | 86.011 | 1.00 | 59.41 | B | O |
| ATOM | 184 | C | GLU | B | 134 | 3.423 | 48.547 | 81.689 | 1.00 | 36.67 | B | C |
| ATOM | 185 | O | GLU | B | 134 | 4.641 | 48.715 | 81.754 | 1.00 | 35.25 | B | O |
| ATOM | 186 | N | ILE | B | 135 | 2.839 | 47.841 | 80.728 | 1.00 | 33.51 | B | N |
| ATOM | 187 | CA | ILE | B | 135 | 3.634 | 47.226 | 79.681 | 1.00 | 31.78 | B | C |
| ATOM | 188 | CB | ILE | B | 135 | 2.782 | 46.261 | 78.800 | 1.00 | 34.95 | B | C |
| ATOM | 189 | CG2 | ILE | B | 135 | 1.761 | 45.538 | 79.666 | 1.00 | 34.31 | B | C |
| ATOM | 190 | CG1 | ILE | B | 135 | 2.080 | 47.031 | 77.678 | 1.00 | 39.33 | B | C |
| ATOM | 191 | CD1 | ILE | B | 135 | 2.645 | 46.764 | 76.280 | 1.00 | 41.33 | B | C |
| ATOM | 192 | C | ILE | B | 135 | 4.285 | 48.294 | 78.808 | 1.00 | 29.27 | B | C |
| ATOM | 193 | O | ILE | B | 135 | 5.359 | 48.078 | 78.259 | 1.00 | 30.63 | B | O |
| ATOM | 194 | N | VAL | B | 136 | 3.644 | 49.450 | 78.672 | 1.00 | 25.60 | B | N |
| ATOM | 195 | CA | VAL | B | 136 | 4.226 | 50.513 | 77.871 | 1.00 | 22.13 | B | C |
| ATOM | 196 | CB | VAL | B | 136 | 3.237 | 51.677 | 77.675 | 1.00 | 20.14 | B | C |
| ATOM | 197 | CG1 | VAL | B | 136 | 3.937 | 52.851 | 77.023 | 1.00 | 19.88 | B | C |
| ATOM | 198 | CG2 | VAL | B | 136 | 2.071 | 51.222 | 76.813 | 1.00 | 20.13 | B | C |
| ATOM | 199 | C | VAL | B | 136 | 5.472 | 51.022 | 78.599 | 1.00 | 22.77 | B | C |
| ATOM | 200 | O | VAL | B | 136 | 6.542 | 51.146 | 78.011 | 1.00 | 21.77 | B | O |
| ATOM | 201 | N | CYS | B | 137 | 5.326 | 51.298 | 79.892 | 1.00 | 21.47 | B | N |
| ATOM | 202 | CA | CYS | B | 137 | 6.424 | 51.794 | 80.716 | 1.00 | 19.12 | B | C |
| ATOM | 203 | CB | CYS | B | 137 | 5.924 | 52.046 | 82.126 | 1.00 | 18.20 | B | C |
| ATOM | 204 | SG | CYS | B | 137 | 5.065 | 53.597 | 82.316 | 1.00 | 27.25 | B | S |
| ATOM | 205 | C | CYS | B | 137 | 7.565 | 50.799 | 80.760 | 1.00 | 18.77 | B | C |
| ATOM | 206 | O | CYS | B | 137 | 8.737 | 51.170 | 80.781 | 1.00 | 16.87 | B | O |
| ATOM | 207 | N | LYS | B | 138 | 7.208 | 49.524 | 80.794 | 1.00 | 19.01 | B | N |
| ATOM | 208 | CA | LYS | B | 138 | 8.205 | 48.468 | 80.822 | 1.00 | 22.36 | B | C |
| ATOM | 209 | CB | LYS | B | 138 | 7.530 | 47.123 | 81.009 | 1.00 | 23.88 | B | C |
| ATOM | 210 | CG | LYS | B | 138 | 7.431 | 46.713 | 82.458 | 1.00 | 31.95 | B | C |
| ATOM | 211 | CD | LYS | B | 138 | 6.385 | 45.629 | 82.645 | 1.00 | 38.85 | B | C |
| ATOM | 212 | CE | LYS | B | 138 | 6.270 | 45.207 | 84.105 | 1.00 | 41.25 | B | C |
| ATOM | 213 | NZ | LYS | B | 138 | 6.809 | 43.828 | 84.313 | 1.00 | 43.92 | B | N |
| ATOM | 214 | C | LYS | B | 138 | 9.002 | 48.462 | 79.531 | 1.00 | 20.08 | B | C |
| ATOM | 215 | O | LYS | B | 138 | 10.221 | 48.325 | 79.551 | 1.00 | 21.21 | B | O |
| ATOM | 216 | N | GLY | B | 139 | 8.296 | 48.630 | 78.417 | 1.00 | 19.40 | B | N |
| ATOM | 217 | CA | GLY | B | 139 | 8.926 | 48.640 | 77.109 | 1.00 | 16.07 | B | C |
| ATOM | 218 | C | GLY | B | 139 | 9.891 | 49.789 | 76.932 | 1.00 | 13.96 | B | C |
| ATOM | 219 | O | GLY | B | 139 | 11.007 | 49.583 | 76.468 | 1.00 | 16.13 | B | O |
| ATOM | 220 | N | LEU | B | 140 | 9.468 | 50.995 | 77.299 | 1.00 | 13.51 | B | N |
| ATOM | 221 | CA | LEU | B | 140 | 10.318 | 52.164 | 77.170 | 1.00 | 13.76 | B | C |
| ATOM | 222 | CB | LEU | B | 140 | 9.534 | 53.424 | 77.535 | 1.00 | 13.91 | B | C |
| ATOM | 223 | CG | LEU | B | 140 | 8.373 | 53.749 | 76.571 | 1.00 | 16.60 | B | C |
| ATOM | 224 | CD1 | LEU | B | 140 | 7.692 | 55.035 | 77.021 | 1.00 | 12.84 | B | C |
| ATOM | 225 | CD2 | LEU | B | 140 | 8.890 | 53.906 | 75.144 | 1.00 | 10.66 | B | C |
| ATOM | 226 | C | LEU | B | 140 | 11.525 | 51.992 | 78.075 | 1.00 | 13.67 | B | C |
| ATOM | 227 | O | LEU | B | 140 | 12.638 | 52.418 | 77.758 | 1.00 | 10.79 | B | O |
| ATOM | 228 | N | TYR | B | 141 | 11.308 | 51.344 | 79.212 | 1.00 | 16.30 | B | N |
| ATOM | 229 | CA | TYR | B | 141 | 12.395 | 51.100 | 80.150 | 1.00 | 15.65 | B | C |
| ATOM | 230 | CB | TYR | B | 141 | 11.858 | 50.460 | 81.429 | 1.00 | 18.25 | B | C |
| ATOM | 231 | CG | TYR | B | 141 | 12.950 | 49.824 | 82.255 | 1.00 | 17.37 | B | C |
| ATOM | 232 | CD1 | TYR | B | 141 | 13.204 | 48.457 | 82.164 | 1.00 | 16.87 | B | C |
| ATOM | 233 | CE1 | TYR | B | 141 | 14.257 | 47.877 | 82.858 | 1.00 | 21.83 | B | C |
| ATOM | 234 | CD2 | TYR | B | 141 | 13.775 | 50.602 | 83.074 | 1.00 | 17.63 | B | C |
| ATOM | 235 | CE2 | TYR | B | 141 | 14.836 | 50.035 | 83.776 | 1.00 | 18.98 | B | C |
| ATOM | 236 | CZ | TYR | B | 141 | 15.077 | 48.666 | 83.661 | 1.00 | 23.23 | B | C |
| ATOM | 237 | OH | TYR | B | 141 | 16.164 | 48.090 | 84.305 | 1.00 | 23.56 | B | O |
| ATOM | 238 | C | TYR | B | 141 | 13.434 | 50.171 | 79.511 | 1.00 | 14.61 | B | C |
| ATOM | 239 | O | TYR | B | 141 | 14.632 | 50.478 | 79.469 | 1.00 | 12.05 | B | O |
| ATOM | 240 | N | ARG | B | 142 | 12.975 | 49.025 | 79.021 | 1.00 | 14.66 | B | N |
| ATOM | 241 | CA | ARG | B | 142 | 13.893 | 48.090 | 78.398 | 1.00 | 16.98 | B | C |
| ATOM | 242 | CB | ARG | B | 142 | 13.161 | 46.809 | 77.968 | 1.00 | 16.06 | B | C |
| ATOM | 243 | CG | ARG | B | 142 | 14.051 | 45.918 | 77.097 | 1.00 | 23.31 | B | C |
| ATOM | 244 | CD | ARG | B | 142 | 13.752 | 44.418 | 77.140 | 1.00 | 23.42 | B | C |
| ATOM | 245 | NE | ARG | B | 142 | 14.778 | 43.712 | 76.357 | 1.00 | 29.80 | B | N |
| ATOM | 246 | CZ | ARG | B | 142 | 14.576 | 42.621 | 75.617 | 1.00 | 31.59 | B | C |
| ATOM | 247 | NH1 | ARG | B | 142 | 13.362 | 42.076 | 75.548 | 1.00 | 30.32 | B | N |
| ATOM | 248 | NH2 | ARG | B | 142 | 15.584 | 42.097 | 74.911 | 1.00 | 23.93 | B | N |
| ATOM | 249 | C | ARG | B | 142 | 14.621 | 48.740 | 77.208 | 1.00 | 17.28 | B | C |
| ATOM | 250 | O | ARG | B | 142 | 15.826 | 48.537 | 77.031 | 1.00 | 18.55 | B | O |
| ATOM | 251 | N | ALA | B | 143 | 13.910 | 49.548 | 76.420 | 1.00 | 15.61 | B | N |
| ATOM | 252 | CA | ALA | B | 143 | 14.532 | 50.206 | 75.266 | 1.00 | 13.78 | B | C |
| ATOM | 253 | CB | ALA | B | 143 | 13.499 | 51.022 | 74.498 | 1.00 | 13.78 | B | C |
| ATOM | 254 | C | ALA | B | 143 | 15.702 | 51.087 | 75.661 | 1.00 | 11.72 | B | C |
| ATOM | 255 | O | ALA | B | 143 | 16.767 | 51.029 | 75.030 | 1.00 | 10.40 | B | O |
| ATOM | 256 | N | LEU | B | 144 | 15.512 | 51.906 | 76.697 | 1.00 | 12.73 | B | N |
| ATOM | 257 | CA | LEU | B | 144 | 16.576 | 52.795 | 77.179 | 1.00 | 12.22 | B | C |
| ATOM | 258 | CB | LEU | B | 144 | 16.027 | 53.764 | 78.230 | 1.00 | 12.36 | B | C |
| ATOM | 259 | CG | LEU | B | 144 | 15.148 | 54.886 | 77.681 | 1.00 | 15.79 | B | C |
| ATOM | 260 | CD1 | LEU | B | 144 | 14.530 | 55.695 | 78.824 | 1.00 | 16.34 | B | C |
| ATOM | 261 | CD2 | LEU | B | 144 | 15.994 | 55.781 | 76.781 | 1.00 | 16.83 | B | C |
| ATOM | 262 | C | LEU | B | 144 | 17.735 | 51.990 | 77.769 | 1.00 | 13.09 | B | C |
| ATOM | 263 | O | LEU | B | 144 | 18.895 | 52.397 | 77.701 | 1.00 | 10.97 | B | O |
| ATOM | 264 | N | CYS | B | 145 | 17.406 | 50.840 | 78.348 | 1.00 | 15.11 | B | N |
| ATOM | 265 | CA | CYS | B | 145 | 18.406 | 49.963 | 78.926 | 1.00 | 16.85 | B | C |
| ATOM | 266 | CB | CYS | B | 145 | 17.738 | 48.835 | 79.698 | 1.00 | 22.34 | B | C |
| ATOM | 267 | SG | CYS | B | 145 | 17.396 | 49.315 | 81.366 | 1.00 | 36.73 | B | S |
| ATOM | 268 | C | CYS | B | 145 | 19.265 | 49.360 | 77.838 | 1.00 | 15.44 | B | C |
| ATOM | 269 | O | CYS | B | 145 | 20.483 | 49.208 | 78.008 | 1.00 | 13.07 | B | O |
| ATOM | 270 | N | ILE | B | 146 | 18.619 | 48.991 | 76.735 | 1.00 | 13.81 | B | N |
| ATOM | 271 | CA | ILE | B | 146 | 19.315 | 48.410 | 75.587 | 1.00 | 14.16 | B | C |
| ATOM | 272 | CB | ILE | B | 146 | 18.304 | 47.972 | 74.498 | 1.00 | 14.31 | B | C |
| ATOM | 273 | CG2 | ILE | B | 146 | 18.983 | 47.867 | 73.138 | 1.00 | 14.84 | B | C |
| ATOM | 274 | CG1 | ILE | B | 146 | 17.689 | 46.628 | 74.883 | 1.00 | 11.65 | B | C |
| ATOM | 275 | CD1 | ILE | B | 146 | 16.384 | 46.333 | 74.144 | 1.00 | 13.42 | B | C |
| ATOM | 276 | C | ILE | B | 146 | 20.316 | 49.419 | 75.001 | 1.00 | 13.49 | B | C |
| ATOM | 277 | O | ILE | B | 146 | 21.481 | 49.081 | 74.764 | 1.00 | 14.08 | B | O |
| ATOM | 278 | N | ARG | B | 147 | 19.878 | 50.662 | 74.806 | 1.00 | 12.60 | B | N |
| ATOM | 279 | CA | ARG | B | 147 | 20.769 | 51.671 | 74.249 | 1.00 | 12.32 | B | C |
| ATOM | 280 | CB | ARG | B | 147 | 20.020 | 52.980 | 73.960 | 1.00 | 6.46 | B | C |
| ATOM | 281 | CG | ARG | B | 147 | 20.963 | 54.136 | 73.625 | 1.00 | 3.42 | B | C |
| ATOM | 282 | CD | ARG | B | 147 | 20.288 | 55.257 | 72.834 | 1.00 | 8.04 | B | C |
| ATOM | 283 | NE | ARG | B | 147 | 21.236 | 56.340 | 72.527 | 1.00 | 10.05 | B | N |
| ATOM | 284 | CZ | ARG | B | 147 | 22.001 | 56.386 | 71.434 | 1.00 | 12.33 | B | C |
| ATOM | 285 | NH1 | ARG | B | 147 | 21.932 | 55.408 | 70.529 | 1.00 | 7.88 | B | N |
| ATOM | 286 | NH2 | ARG | B | 147 | 22.853 | 57.392 | 71.258 | 1.00 | 8.96 | B | N |
| ATOM | 287 | C | ARG | B | 147 | 21.939 | 51.956 | 75.181 | 1.00 | 13.60 | B | C |
| ATOM | 288 | O | ARG | B | 147 | 23.087 | 52.035 | 74.735 | 1.00 | 15.62 | B | O |
| ATOM | 289 | N | GLU | B | 148 | 21.651 | 52.137 | 76.470 | 1.00 | 13.61 | B | N |
| ATOM | 290 | CA | GLU | B | 148 | 22.702 | 52.410 | 77.451 | 1.00 | 12.17 | B | C |
| ATOM | 291 | CB | GLU | B | 148 | 22.108 | 52.528 | 78.863 | 1.00 | 15.56 | B | C |
| ATOM | 292 | CG | GLU | B | 148 | 23.174 | 52.748 | 79.961 | 1.00 | 16.31 | B | C |
| ATOM | 293 | CD | GLU | B | 148 | 22.634 | 52.519 | 81.375 | 1.00 | 20.09 | B | C |
| ATOM | 294 | OE1 | GLU | B | 148 | 22.775 | 53.426 | 82.225 | 1.00 | 17.71 | B | O |
| ATOM | 295 | OE2 | GLU | B | 148 | 22.068 | 51.434 | 81.635 | 1.00 | 20.79 | B | O |
| ATOM | 296 | C | GLU | B | 148 | 23.746 | 51.290 | 77.424 | 1.00 | 11.58 | B | C |
| ATOM | 297 | O | GLU | B | 148 | 24.946 | 51.545 | 77.487 | 1.00 | 12.91 | B | O |
| ATOM | 298 | N | LYS | B | 149 | 23.279 | 50.050 | 77.338 | 1.00 | 11.33 | B | N |
| ATOM | 299 | CA | LYS | B | 149 | 24.164 | 48.893 | 77.295 | 1.00 | 12.50 | B | C |
| ATOM | 300 | CB | LYS | B | 149 | 23.333 | 47.611 | 77.236 | 1.00 | 9.43 | B | C |
| ATOM | 301 | CG | LYS | B | 149 | 24.177 | 46.335 | 77.197 | 1.00 | 11.14 | B | C |
| ATOM | 302 | CD | LYS | B | 149 | 23.322 | 45.077 | 77.226 | 1.00 | 10.75 | B | C |
| ATOM | 303 | CE | LYS | B | 149 | 22.408 | 44.988 | 76.012 | 1.00 | 12.85 | B | C |
| ATOM | 304 | NZ | LYS | B | 149 | 21.728 | 43.660 | 75.944 | 1.00 | 15.82 | B | N |
| ATOM | 305 | C | LYS | B | 149 | 25.130 | 48.931 | 76.096 | 1.00 | 14.20 | B | C |
| ATOM | 306 | O | LYS | B | 149 | 26.350 | 48.788 | 76.248 | 1.00 | 14.36 | B | O |
| ATOM | 307 | N | TYR | B | 150 | 24.588 | 49.133 | 74.900 | 1.00 | 12.65 | B | N |
| ATOM | 308 | CA | TYR | B | 150 | 25.433 | 49.167 | 73.717 | 1.00 | 11.41 | B | C |
| ATOM | 309 | CB | TYR | B | 150 | 24.547 | 49.039 | 72.470 | 1.00 | 15.63 | B | C |
| ATOM | 310 | CG | TYR | B | 150 | 23.986 | 47.637 | 72.340 | 1.00 | 14.38 | B | C |
| ATOM | 311 | CD1 | TYR | B | 150 | 24.816 | 46.569 | 72.026 | 1.00 | 16.00 | B | C |
| ATOM | 312 | CE1 | TYR | B | 150 | 24.332 | 45.254 | 71.990 | 1.00 | 14.45 | B | C |
| ATOM | 313 | CD2 | TYR | B | 150 | 22.653 | 47.365 | 72.606 | 1.00 | 13.19 | B | C |
| ATOM | 314 | CE2 | TYR | B | 150 | 22.162 | 46.055 | 72.568 | 1.00 | 13.58 | B | C |
| ATOM | 315 | CZ | TYR | B | 150 | 23.013 | 45.009 | 72.264 | 1.00 | 13.76 | B | C |
| ATOM | 316 | OH | TYR | B | 150 | 22.557 | 43.711 | 72.273 | 1.00 | 18.24 | B | O |
| ATOM | 317 | C | TYR | B | 150 | 26.328 | 50.395 | 73.665 | 1.00 | 10.37 | B | C |
| ATOM | 318 | O | TYR | B | 150 | 27.458 | 50.339 | 73.162 | 1.00 | 9.80 | B | O |
| ATOM | 319 | N | MET | B | 151 | 25.851 | 51.514 | 74.196 | 1.00 | 9.87 | B | N |
| ATOM | 320 | CA | MET | B | 151 | 26.688 | 52.714 | 74.207 | 1.00 | 13.40 | B | C |
| ATOM | 321 | CB | MET | B | 151 | 25.891 | 53.937 | 74.678 | 1.00 | 11.18 | B | C |
| ATOM | 322 | CG | MET | B | 151 | 24.879 | 54.478 | 73.661 | 1.00 | 15.89 | B | C |
| ATOM | 323 | SD | MET | B | 151 | 25.578 | 54.902 | 72.020 | 1.00 | 11.43 | B | S |
| ATOM | 324 | CE | MET | B | 151 | 25.206 | 53.377 | 71.112 | 1.00 | 8.22 | B | C |
| ATOM | 325 | C | MET | B | 151 | 27.901 | 52.510 | 75.132 | 1.00 | 16.28 | B | C |
| ATOM | 326 | O | MET | B | 151 | 29.054 | 52.646 | 74.707 | 1.00 | 18.54 | B | O |
| ATOM | 327 | N | LEU | B | 152 | 27.638 | 52.176 | 76.394 | 1.00 | 16.57 | B | N |
| ATOM | 328 | CA | LEU | B | 152 | 28.705 | 51.969 | 77.383 | 1.00 | 16.88 | B | C |
| ATOM | 329 | CB | LEU | B | 152 | 28.106 | 51.560 | 78.729 | 1.00 | 19.57 | B | C |
| ATOM | 330 | CG | LEU | B | 152 | 27.163 | 52.565 | 79.406 | 1.00 | 22.95 | B | C |
| ATOM | 331 | CD1 | LEU | B | 152 | 27.031 | 52.213 | 80.882 | 1.00 | 23.45 | B | C |
| ATOM | 332 | CD2 | LEU | B | 152 | 27.689 | 53.981 | 79.230 | 1.00 | 21.93 | B | C |
| ATOM | 333 | C | LEU | B | 152 | 29.721 | 50.923 | 76.957 | 1.00 | 14.98 | B | C |
| ATOM | 334 | O | LEU | B | 152 | 30.929 | 51.133 | 77.092 | 1.00 | 14.87 | B | O |
| ATOM | 335 | N | LYS | B | 153 | 29.236 | 49.804 | 76.433 | 1.00 | 14.05 | B | N |
| ATOM | 336 | CA | LYS | B | 153 | 30.124 | 48.736 | 76.000 | 1.00 | 17.36 | B | C |
| ATOM | 337 | CB | LYS | B | 153 | 29.301 | 47.461 | 75.799 | 1.00 | 19.99 | B | C |
| ATOM | 338 | CG | LYS | B | 153 | 29.404 | 46.828 | 74.449 | 1.00 | 25.27 | B | C |
| ATOM | 339 | CD | LYS | B | 153 | 28.136 | 46.043 | 74.132 | 1.00 | 27.22 | B | C |
| ATOM | 340 | CE | LYS | B | 153 | 27.687 | 45.212 | 75.318 | 1.00 | 30.48 | B | C |
| ATOM | 341 | NZ | LYS | B | 153 | 26.753 | 44.117 | 74.903 | 1.00 | 38.61 | B | N |
| ATOM | 342 | C | LYS | B | 153 | 30.979 | 49.064 | 74.760 | 1.00 | 18.19 | B | C |
| ATOM | 343 | O | LYS | B | 153 | 31.941 | 48.349 | 74.454 | 1.00 | 18.79 | B | O |
| ATOM | 344 | N | SER | B | 154 | 30.656 | 50.156 | 74.066 | 1.00 | 16.61 | B | N |
| ATOM | 345 | CA | SER | B | 154 | 31.426 | 50.552 | 72.887 | 1.00 | 16.42 | B | C |
| ATOM | 346 | CB | SER | B | 154 | 30.525 | 50.633 | 71.653 | 1.00 | 17.09 | B | C |
| ATOM | 347 | OG | SER | B | 154 | 29.506 | 51.606 | 71.814 | 1.00 | 19.15 | B | O |
| ATOM | 348 | C | SER | B | 154 | 32.123 | 51.883 | 73.112 | 1.00 | 16.44 | B | C |
| ATOM | 349 | O | SER | B | 154 | 32.708 | 52.460 | 72.200 | 1.00 | 17.66 | B | O |
| ATOM | 350 | N | PHE | B | 155 | 32.053 | 52.369 | 74.342 | 1.00 | 15.95 | B | N |
| ATOM | 351 | CA | PHE | B | 155 | 32.690 | 53.622 | 74.719 | 1.00 | 15.02 | B | C |
| ATOM | 352 | CB | PHE | B | 155 | 34.189 | 53.543 | 74.465 | 1.00 | 20.54 | B | C |
| ATOM | 353 | CG | PHE | B | 155 | 34.878 | 52.516 | 75.311 | 1.00 | 21.76 | B | C |
| ATOM | 354 | CD1 | PHE | B | 155 | 35.483 | 52.883 | 76.509 | 1.00 | 25.06 | B | C |
| ATOM | 355 | CD2 | PHE | B | 155 | 34.892 | 51.179 | 74.928 | 1.00 | 20.44 | B | C |
| ATOM | 356 | CE1 | PHE | B | 155 | 36.097 | 51.923 | 77.322 | 1.00 | 27.45 | B | C |
| ATOM | 357 | CE2 | PHE | B | 155 | 35.497 | 50.209 | 75.728 | 1.00 | 21.79 | B | C |
| ATOM | 358 | CZ | PHE | B | 155 | 36.101 | 50.580 | 76.926 | 1.00 | 24.41 | B | C |
| ATOM | 359 | C | PHE | B | 155 | 32.109 | 54.839 | 74.032 | 1.00 | 14.89 | B | C |
| ATOM | 360 | O | PHE | B | 155 | 32.823 | 55.816 | 73.731 | 1.00 | 13.15 | B | O |
| ATOM | 361 | N | GLN | B | 156 | 30.804 | 54.779 | 73.799 | 1.00 | 10.42 | B | N |
| ATOM | 362 | CA | GLN | B | 156 | 30.099 | 55.885 | 73.182 | 1.00 | 11.63 | B | C |
| ATOM | 363 | CB | GLN | B | 156 | 29.240 | 55.371 | 72.028 | 1.00 | 11.35 | B | C |
| ATOM | 364 | CG | GLN | B | 156 | 30.086 | 54.815 | 70.893 | 1.00 | 8.89 | B | C |
| ATOM | 365 | CD | GLN | B | 156 | 29.294 | 54.634 | 69.644 | 1.00 | 12.69 | B | C |
| ATOM | 366 | OE1 | GLN | B | 156 | 28.643 | 53.597 | 69.449 | 1.00 | 14.75 | B | O |
| ATOM | 367 | NE2 | GLN | B | 156 | 29.325 | 55.642 | 68.780 | 1.00 | 8.92 | B | N |
| ATOM | 368 | C | GLN | B | 156 | 29.264 | 56.523 | 74.289 | 1.00 | 13.40 | B | C |
| ATOM | 369 | O | GLN | B | 156 | 29.111 | 55.929 | 75.354 | 1.00 | 13.94 | B | O |
| ATOM | 370 | N | ARG | B | 157 | 28.717 | 57.713 | 74.047 | 1.00 | 13.17 | B | N |
| ATOM | 371 | CA | ARG | B | 157 | 27.979 | 58.427 | 75.085 | 1.00 | 12.76 | B | C |
| ATOM | 372 | CB | ARG | B | 157 | 28.174 | 59.926 | 74.883 | 1.00 | 10.08 | B | C |
| ATOM | 373 | CG | ARG | B | 157 | 29.630 | 60.286 | 74.670 | 1.00 | 11.02 | B | C |
| ATOM | 374 | CD | ARG | B | 157 | 29.801 | 61.718 | 74.197 | 1.00 | 16.24 | B | C |
| ATOM | 375 | NE | ARG | B | 157 | 29.331 | 61.904 | 72.823 | 1.00 | 16.76 | B | N |
| ATOM | 376 | CZ | ARG | B | 157 | 29.449 | 63.038 | 72.131 | 1.00 | 16.64 | B | C |
| ATOM | 377 | NH1 | ARG | B | 157 | 28.990 | 63.118 | 70.889 | 1.00 | 17.78 | B | N |
| ATOM | 378 | NH2 | ARG | B | 157 | 30.031 | 64.097 | 72.668 | 1.00 | 14.56 | B | N |
| ATOM | 379 | C | ARG | B | 157 | 26.508 | 58.140 | 75.307 | 1.00 | 14.19 | B | C |
| ATOM | 380 | O | ARG | B | 157 | 25.759 | 57.872 | 74.372 | 1.00 | 18.27 | B | O |
| ATOM | 381 | N | PHE | B | 158 | 26.118 | 58.161 | 76.581 | 1.00 | 13.49 | B | N |
| ATOM | 382 | CA | PHE | B | 158 | 24.732 | 57.986 | 77.009 | 1.00 | 14.17 | B | C |
| ATOM | 383 | CB | PHE | B | 158 | 24.444 | 56.548 | 77.444 | 1.00 | 12.16 | B | C |
| ATOM | 384 | CG | PHE | B | 158 | 22.980 | 56.283 | 77.688 | 1.00 | 14.59 | B | C |
| ATOM | 385 | CD1 | PHE | B | 158 | 22.471 | 56.241 | 78.986 | 1.00 | 9.44 | B | C |
| ATOM | 386 | CD2 | PHE | B | 158 | 22.104 | 56.124 | 76.621 | 1.00 | 11.38 | B | C |
| ATOM | 387 | CE1 | PHE | B | 158 | 21.118 | 56.049 | 79.212 | 1.00 | 8.10 | B | C |
| ATOM | 388 | CE2 | PHE | B | 158 | 20.739 | 55.930 | 76.843 | 1.00 | 13.80 | B | C |
| ATOM | 389 | CZ | PHE | B | 158 | 20.248 | 55.892 | 78.141 | 1.00 | 12.95 | B | C |
| ATOM | 390 | C | PHE | B | 158 | 24.609 | 58.956 | 78.192 | 1.00 | 16.49 | B | C |
| ATOM | 391 | O | PHE | B | 158 | 25.438 | 58.924 | 79.107 | 1.00 | 18.20 | B | O |
| ATOM | 392 | N | PRO | B | 159 | 23.580 | 59.831 | 78.192 | 1.00 | 16.20 | B | N |
| ATOM | 393 | CD | PRO | B | 159 | 22.500 | 59.918 | 77.199 | 1.00 | 14.25 | B | C |
| ATOM | 394 | CA | PRO | B | 159 | 23.400 | 60.808 | 79.276 | 1.00 | 15.28 | B | C |
| ATOM | 395 | CB | PRO | B | 159 | 22.257 | 61.691 | 78.779 | 1.00 | 12.28 | B | C |
| ATOM | 396 | CG | PRO | B | 159 | 21.482 | 60.811 | 77.882 | 1.00 | 17.09 | B | C |
| ATOM | 397 | C | PRO | B | 159 | 23.132 | 60.233 | 80.659 | 1.00 | 14.74 | B | C |
| ATOM | 398 | O | PRO | B | 159 | 22.497 | 59.188 | 80.801 | 1.00 | 17.40 | B | O |
| ATOM | 399 | N | LYS | B | 160 | 23.618 | 60.938 | 81.675 | 1.00 | 15.88 | B | N |
| ATOM | 400 | CA | LYS | B | 160 | 23.459 | 60.531 | 83.074 | 1.00 | 18.09 | B | C |
| ATOM | 401 | CB | LYS | B | 160 | 24.307 | 61.419 | 83.972 | 1.00 | 18.78 | B | C |
| ATOM | 402 | CG | LYS | B | 160 | 25.789 | 61.196 | 83.802 | 1.00 | 28.63 | B | C |
| ATOM | 403 | CD | LYS | B | 160 | 26.614 | 62.230 | 84.576 | 1.00 | 35.06 | B | C |
| ATOM | 404 | CE | LYS | B | 160 | 26.280 | 63.649 | 84.140 | 1.00 | 38.88 | B | C |
| ATOM | 405 | NZ | LYS | B | 160 | 27.152 | 64.099 | 83.012 | 1.00 | 39.06 | B | N |
| ATOM | 406 | C | LYS | B | 160 | 22.040 | 60.532 | 83.622 | 1.00 | 15.93 | B | C |
| ATOM | 407 | O | LYS | B | 160 | 21.623 | 59.557 | 84.244 | 1.00 | 18.32 | B | O |
| ATOM | 408 | N | THR | B | 161 | 21.283 | 61.602 | 83.389 | 1.00 | 17.43 | B | N |
| ATOM | 409 | CA | THR | B | 161 | 19.955 | 61.631 | 83.973 | 1.00 | 18.90 | B | C |
| ATOM | 410 | CB | THR | B | 161 | 19.216 | 62.972 | 83.732 | 1.00 | 19.98 | B | C |
| ATOM | 411 | OG1 | THR | B | 161 | 18.207 | 62.810 | 82.738 | 1.00 | 31.26 | B | O |
| ATOM | 412 | CG2 | THR | B | 161 | 20.184 | 64.050 | 83.356 | 1.00 | 14.69 | B | C |
| ATOM | 413 | C | THR | B | 161 | 19.104 | 60.433 | 83.624 | 1.00 | 18.52 | B | C |
| ATOM | 414 | O | THR | B | 161 | 18.451 | 59.886 | 84.514 | 1.00 | 20.87 | B | O |
| ATOM | 415 | N | PRO | B | 162 | 19.081 | 59.998 | 82.344 | 1.00 | 18.69 | B | N |
| ATOM | 416 | CD | PRO | B | 162 | 19.699 | 60.519 | 81.109 | 1.00 | 16.83 | B | C |
| ATOM | 417 | CA | PRO | B | 162 | 18.243 | 58.812 | 82.094 | 1.00 | 16.36 | B | C |
| ATOM | 418 | CB | PRO | B | 162 | 18.352 | 58.584 | 80.575 | 1.00 | 16.56 | B | C |
| ATOM | 419 | CG | PRO | B | 162 | 18.914 | 59.855 | 80.027 | 1.00 | 17.78 | B | C |
| ATOM | 420 | C | PRO | B | 162 | 18.780 | 57.602 | 82.883 | 1.00 | 15.33 | B | C |
| ATOM | 421 | O | PRO | B | 162 | 18.014 | 56.774 | 83.363 | 1.00 | 14.71 | B | O |
| ATOM | 422 | N | SER | B | 163 | 20.104 | 57.505 | 82.999 | 1.00 | 15.87 | B | N |
| ATOM | 423 | CA | SER | B | 163 | 20.736 | 56.403 | 83.717 | 1.00 | 17.57 | B | C |
| ATOM | 424 | CB | SER | B | 163 | 22.251 | 56.515 | 83.616 | 1.00 | 16.81 | B | C |
| ATOM | 425 | OG | SER | B | 163 | 22.702 | 56.021 | 82.362 | 1.00 | 19.85 | B | O |
| ATOM | 426 | C | SER | B | 163 | 20.310 | 56.404 | 85.177 | 1.00 | 18.31 | B | C |
| ATOM | 427 | O | SER | B | 163 | 19.950 | 55.368 | 85.734 | 1.00 | 20.60 | B | O |
| ATOM | 428 | N | LYS | B | 164 | 20.343 | 57.575 | 85.799 | 1.00 | 19.21 | B | N |
| ATOM | 429 | CA | LYS | B | 164 | 19.925 | 57.691 | 87.191 | 1.00 | 18.65 | B | C |
| ATOM | 430 | CB | LYS | B | 164 | 19.941 | 59.146 | 87.618 | 1.00 | 16.48 | B | C |
| ATOM | 431 | CG | LYS | B | 164 | 21.327 | 59.672 | 87.795 | 1.00 | 17.66 | B | C |
| ATOM | 432 | CD | LYS | B | 164 | 21.306 | 61.163 | 87.978 | 1.00 | 21.03 | B | C |
| ATOM | 433 | CE | LYS | B | 164 | 22.713 | 61.671 | 88.174 | 1.00 | 26.06 | B | C |
| ATOM | 434 | NZ | LYS | B | 164 | 22.710 | 63.121 | 88.492 | 1.00 | 31.81 | B | N |
| ATOM | 435 | C | LYS | B | 164 | 18.523 | 57.121 | 87.360 | 1.00 | 20.08 | B | C |
| ATOM | 436 | O | LYS | B | 164 | 18.261 | 56.391 | 88.314 | 1.00 | 23.54 | B | O |
| ATOM | 437 | N | TYR | B | 165 | 17.616 | 57.443 | 86.441 | 1.00 | 17.33 | B | N |
| ATOM | 438 | CA | TYR | B | 165 | 16.264 | 56.910 | 86.537 | 1.00 | 17.68 | B | C |
| ATOM | 439 | CB | TYR | B | 165 | 15.339 | 57.581 | 85.509 | 1.00 | 16.01 | B | C |
| ATOM | 440 | CG | TYR | B | 165 | 14.710 | 58.853 | 86.010 | 1.00 | 14.81 | B | C |
| ATOM | 441 | CD1 | TYR | B | 165 | 13.596 | 58.819 | 86.837 | 1.00 | 16.96 | B | C |
| ATOM | 442 | CE1 | TYR | B | 165 | 13.024 | 59.990 | 87.327 | 1.00 | 15.54 | B | C |
| ATOM | 443 | CD2 | TYR | B | 165 | 15.243 | 60.090 | 85.680 | 1.00 | 16.54 | B | C |
| ATOM | 444 | CE2 | TYR | B | 165 | 14.687 | 61.261 | 86.161 | 1.00 | 17.83 | B | C |
| ATOM | 445 | CZ | TYR | B | 165 | 13.580 | 61.201 | 86.987 | 1.00 | 17.05 | B | C |
| ATOM | 446 | OH | TYR | B | 165 | 13.049 | 62.362 | 87.491 | 1.00 | 24.58 | B | O |
| ATOM | 447 | C | TYR | B | 165 | 16.237 | 55.398 | 86.330 | 1.00 | 17.39 | B | C |
| ATOM | 448 | O | TYR | B | 165 | 15.413 | 54.712 | 86.921 | 1.00 | 20.26 | B | O |
| ATOM | 449 | N | LEU | B | 166 | 17.123 | 54.878 | 85.482 | 1.00 | 20.54 | B | N |
| ATOM | 450 | CA | LEU | B | 166 | 17.155 | 53.438 | 85.209 | 1.00 | 19.89 | B | C |
| ATOM | 451 | CB | LEU | B | 166 | 18.129 | 53.127 | 84.054 | 1.00 | 19.48 | B | C |
| ATOM | 452 | CG | LEU | B | 166 | 17.759 | 53.624 | 82.637 | 1.00 | 18.59 | B | C |
| ATOM | 453 | CD1 | LEU | B | 166 | 18.890 | 53.323 | 81.679 | 1.00 | 18.50 | B | C |
| ATOM | 454 | CD2 | LEU | B | 166 | 16.477 | 52.951 | 82.148 | 1.00 | 15.66 | B | C |
| ATOM | 455 | C | LEU | B | 166 | 17.592 | 52.719 | 86.481 | 1.00 | 20.23 | B | C |
| ATOM | 456 | O | LEU | B | 166 | 17.013 | 51.706 | 86.869 | 1.00 | 19.60 | B | O |
| ATOM | 457 | N | ARG | B | 167 | 18.615 | 53.263 | 87.131 | 1.00 | 20.13 | B | N |
| ATOM | 458 | CA | ARG | B | 167 | 19.129 | 52.689 | 88.368 | 1.00 | 21.08 | B | C |
| ATOM | 459 | CB | ARG | B | 167 | 20.335 | 53.492 | 88.842 | 1.00 | 16.96 | B | C |
| ATOM | 460 | CG | ARG | B | 167 | 21.587 | 53.368 | 87.970 | 1.00 | 15.36 | B | C |
| ATOM | 461 | CD | ARG | B | 167 | 22.003 | 51.910 | 87.672 | 1.00 | 18.46 | B | C |
| ATOM | 462 | NE | ARG | B | 167 | 21.287 | 51.305 | 86.533 | 1.00 | 22.29 | B | N |
| ATOM | 463 | CZ | ARG | B | 167 | 21.490 | 51.607 | 85.241 | 1.00 | 18.93 | B | C |
| ATOM | 464 | NH1 | ARG | B | 167 | 22.392 | 52.515 | 84.891 | 1.00 | 12.90 | B | N |
| ATOM | 465 | NH2 | ARG | B | 167 | 20.767 | 51.019 | 84.293 | 1.00 | 10.94 | B | N |
| ATOM | 466 | C | ARG | B | 167 | 18.016 | 52.673 | 89.434 | 1.00 | 21.96 | B | C |
| ATOM | 467 | O | ARG | B | 167 | 17.782 | 51.640 | 90.069 | 1.00 | 22.13 | B | O |
| ATOM | 468 | N | SER | B | 168 | 17.316 | 53.801 | 89.596 | 1.00 | 22.75 | B | N |
| ATOM | 469 | CA | SER | B | 168 | 16.202 | 53.922 | 90.554 | 1.00 | 23.84 | B | C |
| ATOM | 470 | CB | SER | B | 168 | 15.538 | 55.282 | 90.454 | 1.00 | 23.84 | B | C |
| ATOM | 471 | OG | SER | B | 168 | 16.437 | 56.288 | 90.835 | 1.00 | 34.52 | B | O |
| ATOM | 472 | C | SER | B | 168 | 15.129 | 52.899 | 90.282 | 1.00 | 24.46 | B | C |
| ATOM | 473 | O | SER | B | 168 | 14.625 | 52.243 | 91.183 | 1.00 | 24.32 | B | O |
| ATOM | 474 | N | ILE | B | 169 | 14.746 | 52.794 | 89.024 | 1.00 | 24.88 | B | N |
| ATOM | 475 | CA | ILE | B | 169 | 13.727 | 51.841 | 88.663 | 1.00 | 25.41 | B | C |
| ATOM | 476 | CB | ILE | B | 169 | 13.430 | 51.932 | 87.156 | 1.00 | 26.59 | B | C |
| ATOM | 477 | CG2 | ILE | B | 169 | 12.776 | 50.648 | 86.664 | 1.00 | 23.71 | B | C |
| ATOM | 478 | CG1 | ILE | B | 169 | 12.549 | 53.155 | 86.886 | 1.00 | 23.62 | B | C |
| ATOM | 479 | CD1 | ILE | B | 169 | 12.423 | 53.497 | 85.423 | 1.00 | 26.71 | B | C |
| ATOM | 480 | C | ILE | B | 169 | 14.192 | 50.433 | 89.033 | 1.00 | 27.08 | B | C |
| ATOM | 481 | O | ILE | B | 169 | 13.391 | 49.594 | 89.437 | 1.00 | 26.69 | B | O |
| ATOM | 482 | N | GLU | B | 170 | 15.492 | 50.183 | 88.912 | 1.00 | 28.65 | B | N |
| ATOM | 483 | CA | GLU | B | 170 | 16.045 | 48.867 | 89.216 | 1.00 | 32.66 | B | C |
| ATOM | 484 | CB | GLU | B | 170 | 17.417 | 48.714 | 88.579 | 1.00 | 30.76 | B | C |
| ATOM | 485 | CG | GLU | B | 170 | 17.361 | 48.460 | 87.094 | 1.00 | 35.21 | B | C |
| ATOM | 486 | CD | GLU | B | 170 | 18.610 | 48.944 | 86.385 | 1.00 | 38.50 | B | C |
| ATOM | 487 | OE1 | GLU | B | 170 | 18.543 | 49.196 | 85.153 | 1.00 | 38.34 | B | O |
| ATOM | 488 | OE2 | GLU | B | 170 | 19.659 | 49.071 | 87.066 | 1.00 | 37.91 | B | O |
| ATOM | 489 | C | GLU | B | 170 | 16.161 | 48.612 | 90.712 | 1.00 | 36.66 | B | C |
| ATOM | 490 | O | GLU | B | 170 | 16.185 | 47.469 | 91.156 | 1.00 | 37.57 | B | O |
| ATOM | 491 | N | GLY | B | 171 | 16.242 | 49.684 | 91.488 | 1.00 | 39.10 | B | N |
| ATOM | 492 | CA | GLY | B | 171 | 16.344 | 49.537 | 92.926 | 1.00 | 40.34 | B | C |
| ATOM | 493 | C | GLY | B | 171 | 17.776 | 49.632 | 93.386 | 1.00 | 41.28 | B | C |
| ATOM | 494 | O | GLY | B | 171 | 18.102 | 49.254 | 94.508 | 1.00 | 44.13 | B | O |
| ATOM | 495 | N | THR | B | 172 | 18.643 | 50.135 | 92.522 | 1.00 | 41.19 | B | N |
| ATOM | 496 | CA | THR | B | 172 | 20.036 | 50.272 | 92.890 | 1.00 | 43.50 | B | C |
| ATOM | 497 | CB | THR | B | 172 | 20.943 | 49.506 | 91.894 | 1.00 | 43.48 | B | C |
| ATOM | 498 | OG1 | THR | B | 172 | 21.247 | 50.332 | 90.768 | 1.00 | 47.24 | B | O |
| ATOM | 499 | CG2 | THR | B | 172 | 20.236 | 48.265 | 91.392 | 1.00 | 43.23 | B | C |
| ATOM | 500 | C | THR | B | 172 | 20.407 | 51.752 | 92.957 | 1.00 | 45.09 | B | C |
| ATOM | 501 | O | THR | B | 172 | 19.652 | 52.616 | 92.499 | 1.00 | 43.93 | B | O |
| ATOM | 502 | N | ALA | B | 173 | 21.559 | 52.043 | 93.555 | 1.00 | 48.58 | B | N |
| ATOM | 503 | CA | ALA | B | 173 | 22.034 | 53.421 | 93.695 | 1.00 | 49.46 | B | C |
| ATOM | 504 | CB | ALA | B | 173 | 22.830 | 53.573 | 94.984 | 1.00 | 50.75 | B | C |
| ATOM | 505 | C | ALA | B | 173 | 22.894 | 53.810 | 92.503 | 1.00 | 49.54 | B | C |
| ATOM | 506 | O | ALA | B | 173 | 23.692 | 53.009 | 92.004 | 1.00 | 50.79 | B | O |
| ATOM | 507 | N | TRP | B | 174 | 22.739 | 55.047 | 92.050 | 1.00 | 48.93 | B | N |
| ATOM | 508 | CA | TRP | B | 174 | 23.481 | 55.513 | 90.894 | 1.00 | 48.87 | B | C |
| ATOM | 509 | CB | TRP | B | 174 | 22.813 | 56.755 | 90.309 | 1.00 | 46.23 | B | C |
| ATOM | 510 | CG | TRP | B | 174 | 23.482 | 57.201 | 89.061 | 1.00 | 46.65 | B | C |
| ATOM | 511 | CD2 | TRP | B | 174 | 24.353 | 58.326 | 88.921 | 1.00 | 46.37 | B | C |
| ATOM | 512 | CE2 | TRP | B | 174 | 24.808 | 58.338 | 87.578 | 1.00 | 44.66 | B | C |
| ATOM | 513 | CE3 | TRP | B | 174 | 24.798 | 59.326 | 89.801 | 1.00 | 45.63 | B | C |
| ATOM | 514 | CD1 | TRP | B | 174 | 23.436 | 56.590 | 87.832 | 1.00 | 44.36 | B | C |
| ATOM | 515 | NE1 | TRP | B | 174 | 24.233 | 57.269 | 86.939 | 1.00 | 43.70 | B | N |
| ATOM | 516 | CZ2 | TRP | B | 174 | 25.686 | 59.315 | 87.093 | 1.00 | 46.58 | B | C |
| ATOM | 517 | CZ3 | TRP | B | 174 | 25.674 | 60.299 | 89.320 | 1.00 | 47.60 | B | C |
| ATOM | 518 | CH2 | TRP | B | 174 | 26.109 | 60.285 | 87.974 | 1.00 | 47.74 | B | C |
| ATOM | 519 | C | TRP | B | 174 | 24.964 | 55.784 | 91.123 | 1.00 | 49.58 | B | C |
| ATOM | 520 | O | TRP | B | 174 | 25.351 | 56.550 | 92.003 | 1.00 | 50.21 | B | O |
| ATOM | 521 | N | LYS | B | 175 | 25.778 | 55.153 | 90.285 | 1.00 | 52.40 | B | N |
| ATOM | 522 | CA | LYS | B | 175 | 27.234 | 55.260 | 90.323 | 1.00 | 52.82 | B | C |
| ATOM | 523 | CB | LYS | B | 175 | 27.850 | 54.107 | 89.528 | 1.00 | 54.22 | B | C |
| ATOM | 524 | CG | LYS | B | 175 | 26.853 | 53.349 | 88.658 | 1.00 | 53.61 | B | C |
| ATOM | 525 | CD | LYS | B | 175 | 27.311 | 51.907 | 88.456 | 1.00 | 58.71 | B | C |
| ATOM | 526 | CE | LYS | B | 175 | 27.490 | 51.164 | 89.796 | 1.00 | 60.87 | B | C |
| ATOM | 527 | NZ | LYS | B | 175 | 28.898 | 51.223 | 90.317 | 1.00 | 58.78 | B | N |
| ATOM | 528 | C | LYS | B | 175 | 27.774 | 56.569 | 89.764 | 1.00 | 52.30 | B | C |
| ATOM | 529 | O | LYS | B | 175 | 27.357 | 57.655 | 90.156 | 1.00 | 55.47 | B | O |
| ATOM | 530 | N | ALA | B | 176 | 28.722 | 56.437 | 88.845 | 1.00 | 51.83 | B | N |
| ATOM | 531 | CA | ALA | B | 176 | 29.365 | 57.567 | 88.199 | 1.00 | 52.86 | B | C |
| ATOM | 532 | CB | ALA | B | 176 | 29.857 | 58.563 | 89.245 | 1.00 | 49.34 | B | C |
| ATOM | 533 | C | ALA | B | 176 | 30.543 | 57.021 | 87.390 | 1.00 | 54.22 | B | C |
| ATOM | 534 | O | ALA | B | 176 | 31.345 | 57.786 | 86.849 | 1.00 | 56.23 | B | O |
| ATOM | 535 | N | ASN | B | 177 | 30.637 | 55.693 | 87.309 | 1.00 | 55.37 | B | N |
| ATOM | 536 | CA | ASN | B | 177 | 31.720 | 55.025 | 86.572 | 1.00 | 56.17 | B | C |
| ATOM | 537 | CB | ASN | B | 177 | 31.326 | 53.581 | 86.242 | 1.00 | 56.10 | B | C |
| ATOM | 538 | CG | ASN | B | 177 | 30.117 | 53.489 | 85.316 | 1.00 | 58.22 | B | C |
| ATOM | 539 | OD1 | ASN | B | 177 | 29.014 | 53.921 | 85.667 | 1.00 | 61.16 | B | O |
| ATOM | 540 | ND2 | ASN | B | 177 | 30.320 | 52.915 | 84.129 | 1.00 | 56.36 | B | N |
| ATOM | 541 | C | ASN | B | 177 | 32.151 | 55.743 | 85.285 | 1.00 | 54.69 | B | C |
| ATOM | 542 | O | ASN | B | 177 | 31.389 | 55.848 | 84.317 | 1.00 | 53.93 | B | O |
| ATOM | 543 | N | GLU | B | 178 | 33.387 | 56.229 | 85.284 | 1.00 | 52.70 | B | N |
| ATOM | 544 | CA | GLU | B | 178 | 33.919 | 56.936 | 84.134 | 1.00 | 51.38 | B | C |
| ATOM | 545 | CB | GLU | B | 178 | 34.747 | 58.132 | 84.605 | 1.00 | 52.69 | B | C |
| ATOM | 546 | CG | GLU | B | 178 | 33.907 | 59.312 | 85.093 | 1.00 | 56.95 | B | C |
| ATOM | 547 | CD | GLU | B | 178 | 32.786 | 59.698 | 84.120 | 1.00 | 60.87 | B | C |
| ATOM | 548 | OE1 | GLU | B | 178 | 32.077 | 58.789 | 83.630 | 1.00 | 60.80 | B | O |
| ATOM | 549 | OE2 | GLU | B | 178 | 32.609 | 60.911 | 83.849 | 1.00 | 61.36 | B | O |
| ATOM | 550 | C | GLU | B | 178 | 34.764 | 56.033 | 83.242 | 1.00 | 50.44 | B | C |
| ATOM | 551 | O | GLU | B | 178 | 35.383 | 56.498 | 82.273 | 1.00 | 51.53 | B | O |
| ATOM | 552 | N | SER | B | 179 | 34.775 | 54.742 | 83.560 | 1.00 | 46.90 | B | N |
| ATOM | 553 | CA | SER | B | 179 | 35.553 | 53.774 | 82.796 | 1.00 | 43.96 | B | C |
| ATOM | 554 | CB | SER | B | 179 | 35.508 | 52.409 | 83.482 | 1.00 | 43.41 | B | C |
| ATOM | 555 | OG | SER | B | 179 | 34.292 | 52.231 | 84.184 | 1.00 | 43.78 | B | O |
| ATOM | 556 | C | SER | B | 179 | 35.104 | 53.615 | 81.344 | 1.00 | 42.68 | B | C |
| ATOM | 557 | O | SER | B | 179 | 35.944 | 53.463 | 80.449 | 1.00 | 43.64 | B | O |
| ATOM | 558 | N | SER | B | 180 | 33.791 | 53.664 | 81.110 | 1.00 | 39.55 | B | N |
| ATOM | 559 | CA | SER | B | 180 | 33.238 | 53.484 | 79.763 | 1.00 | 38.56 | B | C |
| ATOM | 560 | CB | SER | B | 180 | 31.841 | 52.880 | 79.852 | 1.00 | 38.03 | B | C |
| ATOM | 561 | OG | SER | B | 180 | 31.794 | 51.877 | 80.842 | 1.00 | 40.73 | B | O |
| ATOM | 562 | C | SER | B | 180 | 33.160 | 54.752 | 78.928 | 1.00 | 37.54 | B | C |
| ATOM | 563 | O | SER | B | 180 | 32.543 | 54.773 | 77.862 | 1.00 | 37.36 | B | O |
| ATOM | 564 | N | TYR | B | 181 | 33.787 | 55.806 | 79.419 | 1.00 | 35.83 | B | N |
| ATOM | 565 | CA | TYR | B | 181 | 33.783 | 57.091 | 78.748 | 1.00 | 34.75 | B | C |
| ATOM | 566 | CB | TYR | B | 181 | 34.344 | 58.133 | 79.697 | 1.00 | 39.95 | B | C |
| ATOM | 567 | CG | TYR | B | 181 | 33.370 | 59.200 | 80.095 | 1.00 | 46.42 | B | C |
| ATOM | 568 | CD1 | TYR | B | 181 | 33.590 | 60.535 | 79.739 | 1.00 | 49.59 | B | C |
| ATOM | 569 | CE1 | TYR | B | 181 | 32.713 | 61.542 | 80.138 | 1.00 | 54.50 | B | C |
| ATOM | 570 | CD2 | TYR | B | 181 | 32.247 | 58.889 | 80.856 | 1.00 | 49.17 | B | C |
| ATOM | 571 | CE2 | TYR | B | 181 | 31.354 | 59.888 | 81.265 | 1.00 | 54.38 | B | C |
| ATOM | 572 | CZ | TYR | B | 181 | 31.591 | 61.215 | 80.906 | 1.00 | 56.27 | B | C |
| ATOM | 573 | OH | TYR | B | 181 | 30.716 | 62.210 | 81.319 | 1.00 | 57.87 | B | O |
| ATOM | 574 | C | TYR | B | 181 | 34.620 | 57.092 | 77.484 | 1.00 | 31.88 | B | C |
| ATOM | 575 | O | TYR | B | 181 | 35.668 | 56.472 | 77.444 | 1.00 | 30.73 | B | O |
| ATOM | 576 | N | PRO | B | 182 | 34.152 | 57.769 | 76.420 | 1.00 | 31.04 | B | N |
| ATOM | 577 | CD | PRO | B | 182 | 32.873 | 58.481 | 76.275 | 1.00 | 29.38 | B | C |
| ATOM | 578 | CA | PRO | B | 182 | 34.945 | 57.804 | 75.185 | 1.00 | 30.71 | B | C |
| ATOM | 579 | CB | PRO | B | 182 | 34.059 | 58.573 | 74.203 | 1.00 | 29.41 | B | C |
| ATOM | 580 | CG | PRO | B | 182 | 33.078 | 59.302 | 75.042 | 1.00 | 30.01 | B | C |
| ATOM | 581 | C | PRO | B | 182 | 36.252 | 58.544 | 75.485 | 1.00 | 30.98 | B | C |
| ATOM | 582 | O | PRO | B | 182 | 36.285 | 59.386 | 76.380 | 1.00 | 33.34 | B | O |
| ATOM | 583 | N | VAL | B | 183 | 37.327 | 58.233 | 74.765 | 1.00 | 28.87 | B | N |
| ATOM | 584 | CA | VAL | B | 183 | 38.606 | 58.904 | 75.004 | 1.00 | 26.13 | B | C |
| ATOM | 585 | CB | VAL | B | 183 | 39.730 | 57.885 | 75.275 | 1.00 | 28.13 | B | C |
| ATOM | 586 | CG1 | VAL | B | 183 | 41.039 | 58.611 | 75.531 | 1.00 | 28.69 | B | C |
| ATOM | 587 | CG2 | VAL | B | 183 | 39.369 | 57.003 | 76.458 | 1.00 | 25.64 | B | C |
| ATOM | 588 | C | VAL | B | 183 | 39.011 | 59.752 | 73.809 | 1.00 | 26.08 | B | C |
| ATOM | 589 | O | VAL | B | 183 | 39.460 | 59.215 | 72.800 | 1.00 | 26.15 | B | O |
| ATOM | 590 | N | PHE | B | 184 | 38.839 | 61.069 | 73.915 | 1.00 | 25.86 | B | N |
| ATOM | 591 | CA | PHE | B | 184 | 39.191 | 61.981 | 72.830 | 1.00 | 30.85 | B | C |
| ATOM | 592 | CB | PHE | B | 184 | 38.337 | 63.245 | 72.886 | 1.00 | 35.65 | B | C |
| ATOM | 593 | CG | PHE | B | 184 | 36.894 | 63.014 | 72.540 | 1.00 | 42.83 | B | C |
| ATOM | 594 | CD1 | PHE | B | 184 | 36.399 | 63.362 | 71.274 | 1.00 | 45.52 | B | C |
| ATOM | 595 | CD2 | PHE | B | 184 | 36.030 | 62.427 | 73.471 | 1.00 | 41.01 | B | C |
| ATOM | 596 | CE1 | PHE | B | 184 | 35.054 | 63.125 | 70.942 | 1.00 | 48.84 | B | C |
| ATOM | 597 | CE2 | PHE | B | 184 | 34.689 | 62.185 | 73.155 | 1.00 | 44.48 | B | C |
| ATOM | 598 | CZ | PHE | B | 184 | 34.196 | 62.534 | 71.887 | 1.00 | 46.83 | B | C |
| ATOM | 599 | C | PHE | B | 184 | 40.641 | 62.361 | 72.997 | 1.00 | 31.22 | B | C |
| ATOM | 600 | O | PHE | B | 184 | 41.093 | 62.557 | 74.121 | 1.00 | 30.48 | B | O |
| ATOM | 601 | N | THR | B | 185 | 41.390 | 62.474 | 71.907 | 1.00 | 29.89 | B | N |
| ATOM | 602 | CA | THR | B | 185 | 42.783 | 62.825 | 72.107 | 1.00 | 30.70 | B | C |
| ATOM | 603 | CB | THR | B | 185 | 43.645 | 62.665 | 70.793 | 1.00 | 29.58 | B | C |
| ATOM | 604 | OG1 | THR | B | 185 | 44.124 | 63.935 | 70.349 | 1.00 | 31.46 | B | O |
| ATOM | 605 | CG2 | THR | B | 185 | 42.863 | 61.987 | 69.713 | 1.00 | 24.40 | B | C |
| ATOM | 606 | C | THR | B | 185 | 42.853 | 64.235 | 72.704 | 1.00 | 31.37 | B | C |
| ATOM | 607 | O | THR | B | 185 | 42.053 | 65.116 | 72.364 | 1.00 | 29.64 | B | O |
| ATOM | 608 | N | PRO | B | 186 | 43.776 | 64.441 | 73.663 | 1.00 | 31.30 | B | N |
| ATOM | 609 | CD | PRO | B | 186 | 44.691 | 63.412 | 74.183 | 1.00 | 28.41 | B | C |
| ATOM | 610 | CA | PRO | B | 186 | 43.964 | 65.732 | 74.336 | 1.00 | 29.78 | B | C |
| ATOM | 611 | CB | PRO | B | 186 | 45.072 | 65.455 | 75.349 | 1.00 | 28.15 | B | C |
| ATOM | 612 | CG | PRO | B | 186 | 45.729 | 64.213 | 74.882 | 1.00 | 30.38 | B | C |
| ATOM | 613 | C | PRO | B | 186 | 44.328 | 66.869 | 73.399 | 1.00 | 29.34 | B | C |
| ATOM | 614 | O | PRO | B | 186 | 45.019 | 66.672 | 72.404 | 1.00 | 33.14 | B | O |
| ATOM | 615 | N | ALA | B | 187 | 43.850 | 68.062 | 73.718 | 1.00 | 27.92 | B | N |
| ATOM | 616 | CA | ALA | B | 187 | 44.144 | 69.230 | 72.907 | 1.00 | 30.56 | B | C |
| ATOM | 617 | CB | ALA | B | 187 | 43.521 | 70.464 | 73.541 | 1.00 | 24.06 | B | C |
| ATOM | 618 | C | ALA | B | 187 | 45.655 | 69.396 | 72.838 | 1.00 | 33.70 | B | C |
| ATOM | 619 | O | ALA | B | 187 | 46.337 | 69.203 | 73.837 | 1.00 | 36.09 | B | O |
| ATOM | 620 | N | LEU | B | 188 | 46.209 | 69.729 | 71.678 | 1.00 | 37.85 | B | N |
| ATOM | 621 | CA | LEU | B | 188 | 47.648 | 69.918 | 71.676 | 1.00 | 39.72 | B | C |
| ATOM | 622 | CB | LEU | B | 188 | 48.272 | 69.734 | 70.284 | 1.00 | 39.87 | B | C |
| ATOM | 623 | CG | LEU | B | 188 | 47.697 | 70.303 | 68.998 | 1.00 | 41.73 | B | C |
| ATOM | 624 | CD1 | LEU | B | 188 | 48.680 | 71.291 | 68.404 | 1.00 | 39.58 | B | C |
| ATOM | 625 | CD2 | LEU | B | 188 | 47.438 | 69.157 | 68.023 | 1.00 | 42.51 | B | C |
| ATOM | 626 | C | LEU | B | 188 | 47.905 | 71.314 | 72.216 | 1.00 | 40.05 | B | C |
| ATOM | 627 | O | LEU | B | 188 | 47.079 | 72.215 | 72.052 | 1.00 | 37.28 | B | O |
| ATOM | 628 | N | LYS | B | 189 | 49.036 | 71.466 | 72.899 | 1.00 | 42.57 | B | N |
| ATOM | 629 | CA | LYS | B | 189 | 49.430 | 72.737 | 73.490 | 1.00 | 46.11 | B | C |
| ATOM | 630 | CB | LYS | B | 189 | 50.711 | 72.555 | 74.275 | 1.00 | 44.21 | B | C |
| ATOM | 631 | CG | LYS | B | 189 | 50.731 | 71.262 | 75.061 | 1.00 | 45.87 | B | C |
| ATOM | 632 | CD | LYS | B | 189 | 50.314 | 71.503 | 76.503 | 1.00 | 50.48 | B | C |
| ATOM | 633 | CE | LYS | B | 189 | 49.112 | 70.657 | 76.889 | 1.00 | 50.78 | B | C |
| ATOM | 634 | NZ | LYS | B | 189 | 49.264 | 70.100 | 78.265 | 1.00 | 51.47 | B | N |
| ATOM | 635 | C | LYS | B | 189 | 49.633 | 73.831 | 72.459 | 1.00 | 50.56 | B | C |
| ATOM | 636 | O | LYS | B | 189 | 49.748 | 73.557 | 71.260 | 1.00 | 51.05 | B | O |
| ATOM | 637 | N | LYS | B | 190 | 49.671 | 75.075 | 72.936 | 1.00 | 54.45 | B | N |
| ATOM | 638 | CA | LYS | B | 190 | 49.862 | 76.228 | 72.059 | 1.00 | 56.98 | B | C |
| ATOM | 639 | CB | LYS | B | 190 | 50.020 | 77.512 | 72.894 | 1.00 | 58.19 | B | C |
| ATOM | 640 | CG | LYS | B | 190 | 49.941 | 78.823 | 72.101 | 1.00 | 58.21 | B | C |
| ATOM | 641 | CD | LYS | B | 190 | 51.151 | 79.721 | 72.387 | 1.00 | 59.83 | B | C |
| ATOM | 642 | CE | LYS | B | 190 | 51.328 | 80.001 | 73.882 | 1.00 | 58.63 | B | C |
| ATOM | 643 | NZ | LYS | B | 190 | 52.744 | 79.860 | 74.308 | 1.00 | 59.05 | B | N |
| ATOM | 644 | C | LYS | B | 190 | 51.124 | 75.954 | 71.246 | 1.00 | 56.71 | B | C |
| ATOM | 645 | O | LYS | B | 190 | 52.213 | 75.760 | 71.815 | 1.00 | 54.34 | B | O |
| ATOM | 646 | N | GLY | B | 191 | 50.969 | 75.913 | 69.922 | 1.00 | 56.83 | B | N |
| ATOM | 647 | CA | GLY | B | 191 | 52.109 | 75.643 | 69.063 | 1.00 | 56.16 | B | C |
| ATOM | 648 | C | GLY | B | 191 | 52.851 | 74.380 | 69.490 | 1.00 | 54.79 | B | C |
| ATOM | 649 | O | GLY | B | 191 | 53.880 | 74.429 | 70.171 | 1.00 | 51.87 | B | O |
| ATOM | 650 | N | GLU | B | 192 | 52.299 | 73.234 | 69.107 | 1.00 | 53.02 | B | N |
| ATOM | 651 | CA | GLU | B | 192 | 52.903 | 71.937 | 69.410 | 1.00 | 47.83 | B | C |
| ATOM | 652 | CB | GLU | B | 192 | 52.150 | 71.230 | 70.534 | 1.00 | 46.17 | B | C |
| ATOM | 653 | CG | GLU | B | 192 | 52.726 | 69.873 | 70.898 | 1.00 | 42.51 | B | C |
| ATOM | 654 | CD | GLU | B | 192 | 51.729 | 68.998 | 71.667 | 1.00 | 44.74 | B | C |
| ATOM | 655 | OE1 | GLU | B | 192 | 52.004 | 67.792 | 71.849 | 1.00 | 42.29 | B | O |
| ATOM | 656 | OE2 | GLU | B | 192 | 50.667 | 69.508 | 72.092 | 1.00 | 44.57 | B | O |
| ATOM | 657 | C | GLU | B | 192 | 52.755 | 71.158 | 68.120 | 1.00 | 43.97 | B | C |
| ATOM | 658 | O | GLU | B | 192 | 51.754 | 71.317 | 67.416 | 1.00 | 47.24 | B | O |
| ATOM | 659 | N | ASP | B | 193 | 53.740 | 70.328 | 67.800 | 1.00 | 39.73 | B | N |
| ATOM | 660 | CA | ASP | B | 193 | 53.681 | 69.575 | 66.553 | 1.00 | 36.49 | B | C |
| ATOM | 661 | CB | ASP | B | 193 | 54.972 | 68.808 | 66.318 | 1.00 | 36.15 | B | C |
| ATOM | 662 | CG | ASP | B | 193 | 54.966 | 68.074 | 64.994 | 1.00 | 39.51 | B | C |
| ATOM | 663 | OD1 | ASP | B | 193 | 55.158 | 66.849 | 65.013 | 1.00 | 40.76 | B | O |
| ATOM | 664 | OD2 | ASP | B | 193 | 54.760 | 68.712 | 63.935 | 1.00 | 43.43 | B | O |
| ATOM | 665 | C | ASP | B | 193 | 52.504 | 68.619 | 66.528 | 1.00 | 32.19 | B | C |
| ATOM | 666 | O | ASP | B | 193 | 52.448 | 67.664 | 67.310 | 1.00 | 29.08 | B | O |
| ATOM | 667 | N | PRO | B | 194 | 51.552 | 68.856 | 65.611 | 1.00 | 28.04 | B | N |
| ATOM | 668 | CD | PRO | B | 194 | 51.523 | 69.916 | 64.588 | 1.00 | 27.97 | B | C |
| ATOM | 669 | CA | PRO | B | 194 | 50.387 | 67.976 | 65.539 | 1.00 | 25.56 | B | C |
| ATOM | 670 | CB | PRO | B | 194 | 49.436 | 68.686 | 64.566 | 1.00 | 25.83 | B | C |
| ATOM | 671 | CG | PRO | B | 194 | 50.078 | 70.007 | 64.237 | 1.00 | 29.03 | B | C |
| ATOM | 672 | C | PRO | B | 194 | 50.747 | 66.582 | 65.058 | 1.00 | 24.19 | B | C |
| ATOM | 673 | O | PRO | B | 194 | 49.947 | 65.659 | 65.180 | 1.00 | 21.98 | B | O |
| ATOM | 674 | N | PHE | B | 195 | 51.957 | 66.415 | 64.536 | 1.00 | 24.81 | B | N |
| ATOM | 675 | CA | PHE | B | 195 | 52.332 | 65.114 | 64.002 | 1.00 | 27.97 | B | C |
| ATOM | 676 | CB | PHE | B | 195 | 52.628 | 65.249 | 62.503 | 1.00 | 25.59 | B | C |
| ATOM | 677 | CG | PHE | B | 195 | 51.538 | 65.962 | 61.750 | 1.00 | 23.68 | B | C |
| ATOM | 678 | CD1 | PHE | B | 195 | 50.365 | 65.292 | 61.404 | 1.00 | 21.03 | B | C |
| ATOM | 679 | CD2 | PHE | B | 195 | 51.657 | 67.318 | 61.450 | 1.00 | 21.17 | B | C |
| ATOM | 680 | CE1 | PHE | B | 195 | 49.321 | 65.970 | 60.774 | 1.00 | 20.97 | B | C |
| ATOM | 681 | CE2 | PHE | B | 195 | 50.623 | 67.998 | 60.825 | 1.00 | 21.40 | B | C |
| ATOM | 682 | CZ | PHE | B | 195 | 49.453 | 67.324 | 60.486 | 1.00 | 20.62 | B | C |
| ATOM | 683 | C | PHE | B | 195 | 53.467 | 64.406 | 64.704 | 1.00 | 30.22 | B | C |
| ATOM | 684 | O | PHE | B | 195 | 54.111 | 63.530 | 64.113 | 1.00 | 30.04 | B | O |
| ATOM | 685 | N | ARG | B | 196 | 53.687 | 64.768 | 65.971 | 1.00 | 33.46 | B | N |
| ATOM | 686 | CA | ARG | B | 196 | 54.744 | 64.166 | 66.789 | 1.00 | 34.38 | B | C |
| ATOM | 687 | CB | ARG | B | 196 | 54.643 | 64.646 | 68.232 | 1.00 | 35.20 | B | C |
| ATOM | 688 | CG | ARG | B | 196 | 54.789 | 66.146 | 68.343 | 1.00 | 44.55 | B | C |
| ATOM | 689 | CD | ARG | B | 196 | 54.771 | 66.602 | 69.785 | 1.00 | 48.23 | B | C |
| ATOM | 690 | NE | ARG | B | 196 | 55.481 | 65.675 | 70.666 | 1.00 | 51.25 | B | N |
| ATOM | 691 | CZ | ARG | B | 196 | 55.870 | 65.981 | 71.902 | 1.00 | 52.32 | B | C |
| ATOM | 692 | NH1 | ARG | B | 196 | 55.616 | 67.187 | 72.403 | 1.00 | 53.40 | B | N |
| ATOM | 693 | NH2 | ARG | B | 196 | 56.516 | 65.088 | 72.640 | 1.00 | 51.81 | B | N |
| ATOM | 694 | C | ARG | B | 196 | 54.681 | 62.654 | 66.764 | 1.00 | 35.14 | B | C |
| ATOM | 695 | O | ARG | B | 196 | 53.617 | 62.047 | 66.844 | 1.00 | 36.27 | B | O |
| ATOM | 696 | N | THR | B | 197 | 55.838 | 62.036 | 66.657 | 1.00 | 36.28 | B | N |
| ATOM | 697 | CA | THR | B | 197 | 55.882 | 60.595 | 66.616 | 1.00 | 36.64 | B | C |
| ATOM | 698 | CB | THR | B | 197 | 56.411 | 60.145 | 65.255 | 1.00 | 37.06 | B | C |
| ATOM | 699 | OG1 | THR | B | 197 | 56.022 | 58.791 | 65.018 | 1.00 | 41.27 | B | O |
| ATOM | 700 | CG2 | THR | B | 197 | 57.923 | 60.275 | 65.202 | 1.00 | 34.66 | B | C |
| ATOM | 701 | C | THR | B | 197 | 56.751 | 60.030 | 67.746 | 1.00 | 37.32 | B | C |
| ATOM | 702 | O | THR | B | 197 | 57.020 | 58.828 | 67.794 | 1.00 | 38.29 | B | O |
| ATOM | 703 | N | ASP | B | 198 | 57.165 | 60.897 | 68.666 | 1.00 | 36.66 | B | N |
| ATOM | 704 | CA | ASP | B | 198 | 58.008 | 60.485 | 69.779 | 1.00 | 37.91 | B | C |
| ATOM | 705 | CB | ASP | B | 198 | 58.874 | 61.664 | 70.230 | 1.00 | 38.89 | B | C |
| ATOM | 706 | CG | ASP | B | 198 | 58.059 | 62.856 | 70.679 | 1.00 | 41.54 | B | C |
| ATOM | 707 | OD1 | ASP | B | 198 | 57.375 | 63.476 | 69.835 | 1.00 | 45.32 | B | O |
| ATOM | 708 | OD2 | ASP | B | 198 | 58.112 | 63.179 | 71.884 | 1.00 | 43.11 | B | O |
| ATOM | 709 | C | ASP | B | 198 | 57.260 | 59.918 | 70.984 | 1.00 | 38.41 | B | C |
| ATOM | 710 | O | ASP | B | 198 | 57.875 | 59.402 | 71.914 | 1.00 | 40.34 | B | O |
| ATOM | 711 | N | ASN | B | 199 | 55.936 | 59.984 | 70.959 | 1.00 | 39.32 | B | N |
| ATOM | 712 | CA | ASN | B | 199 | 55.123 | 59.521 | 72.080 | 1.00 | 36.67 | B | C |
| ATOM | 713 | CB | ASN | B | 199 | 54.215 | 60.663 | 72.522 | 1.00 | 38.64 | B | C |
| ATOM | 714 | CG | ASN | B | 199 | 53.722 | 61.500 | 71.339 | 1.00 | 44.07 | B | C |
| ATOM | 715 | OD1 | ASN | B | 199 | 53.418 | 62.690 | 71.487 | 1.00 | 48.29 | B | O |
| ATOM | 716 | ND2 | ASN | B | 199 | 53.647 | 60.879 | 70.154 | 1.00 | 38.14 | B | N |
| ATOM | 717 | C | ASN | B | 199 | 54.269 | 58.282 | 71.809 | 1.00 | 35.15 | B | C |
| ATOM | 718 | O | ASN | B | 199 | 53.372 | 57.967 | 72.587 | 1.00 | 36.49 | B | O |
| ATOM | 719 | N | LEU | B | 200 | 54.543 | 57.571 | 70.722 | 1.00 | 31.23 | B | N |
| ATOM | 720 | CA | LEU | B | 200 | 53.763 | 56.392 | 70.395 | 1.00 | 28.64 | B | C |
| ATOM | 721 | CB | LEU | B | 200 | 53.936 | 56.059 | 68.914 | 1.00 | 31.35 | B | C |
| ATOM | 722 | CG | LEU | B | 200 | 53.536 | 57.099 | 67.864 | 1.00 | 29.87 | B | C |
| ATOM | 723 | CD1 | LEU | B | 200 | 54.018 | 56.636 | 66.505 | 1.00 | 24.89 | B | C |
| ATOM | 724 | CD2 | LEU | B | 200 | 52.028 | 57.279 | 67.853 | 1.00 | 28.03 | B | C |
| ATOM | 725 | C | LEU | B | 200 | 54.138 | 55.165 | 71.228 | 1.00 | 28.93 | B | C |
| ATOM | 726 | O | LEU | B | 200 | 55.310 | 54.937 | 71.514 | 1.00 | 29.26 | B | O |
| ATOM | 727 | N | PRO | B | 201 | 53.140 | 54.354 | 71.624 | 1.00 | 28.99 | B | N |
| ATOM | 728 | CD | PRO | B | 201 | 51.708 | 54.574 | 71.355 | 1.00 | 26.92 | B | C |
| ATOM | 729 | CA | PRO | B | 201 | 53.350 | 53.137 | 72.420 | 1.00 | 28.55 | B | C |
| ATOM | 730 | CB | PRO | B | 201 | 51.937 | 52.612 | 72.665 | 1.00 | 25.95 | B | C |
| ATOM | 731 | CG | PRO | B | 201 | 51.050 | 53.766 | 72.423 | 1.00 | 24.96 | B | C |
| ATOM | 732 | C | PRO | B | 201 | 54.210 | 52.101 | 71.695 | 1.00 | 30.96 | B | C |
| ATOM | 733 | O | PRO | B | 201 | 54.439 | 52.210 | 70.495 | 1.00 | 31.99 | B | O |
| ATOM | 734 | N | GLU | B | 202 | 54.675 | 51.095 | 72.427 | 1.00 | 30.73 | B | N |
| ATOM | 735 | CA | GLU | B | 202 | 55.510 | 50.054 | 71.840 | 1.00 | 34.79 | B | C |
| ATOM | 736 | CB | GLU | B | 202 | 56.340 | 49.360 | 72.928 | 1.00 | 40.19 | B | C |
| ATOM | 737 | CG | GLU | B | 202 | 56.835 | 50.289 | 74.037 | 1.00 | 49.91 | B | C |
| ATOM | 738 | CD | GLU | B | 202 | 57.457 | 49.534 | 75.217 | 1.00 | 56.19 | B | C |
| ATOM | 739 | OE1 | GLU | B | 202 | 56.714 | 48.834 | 75.951 | 1.00 | 57.73 | B | O |
| ATOM | 740 | OE2 | GLU | B | 202 | 58.694 | 49.644 | 75.410 | 1.00 | 58.67 | B | O |
| ATOM | 741 | C | GLU | B | 202 | 54.654 | 49.019 | 71.124 | 1.00 | 33.18 | B | C |
| ATOM | 742 | O | GLU | B | 202 | 53.471 | 48.883 | 71.416 | 1.00 | 32.31 | B | O |
| ATOM | 743 | N | ASN | B | 203 | 55.250 | 48.292 | 70.184 | 1.00 | 31.62 | B | N |
| ATOM | 744 | CA | ASN | B | 203 | 54.521 | 47.266 | 69.449 | 1.00 | 31.12 | B | C |
| ATOM | 745 | CB | ASN | B | 203 | 55.333 | 46.793 | 68.241 | 1.00 | 31.31 | B | C |
| ATOM | 746 | CG | ASN | B | 203 | 55.616 | 47.910 | 67.256 | 1.00 | 29.55 | B | C |
| ATOM | 747 | OD1 | ASN | B | 203 | 56.627 | 47.900 | 66.563 | 1.00 | 31.17 | B | O |
| ATOM | 748 | ND2 | ASN | B | 203 | 54.726 | 48.878 | 67.196 | 1.00 | 28.33 | B | N |
| ATOM | 749 | C | ASN | B | 203 | 54.248 | 46.097 | 70.378 | 1.00 | 30.97 | B | C |
| ATOM | 750 | O | ASN | B | 203 | 55.026 | 45.833 | 71.292 | 1.00 | 33.34 | B | O |
| ATOM | 751 | N | LEU | B | 204 | 53.142 | 45.399 | 70.157 | 1.00 | 31.70 | B | N |
| ATOM | 752 | CA | LEU | B | 204 | 52.785 | 44.258 | 71.002 | 1.00 | 33.51 | B | C |
| ATOM | 753 | CB | LEU | B | 204 | 51.404 | 44.455 | 71.628 | 1.00 | 32.29 | B | C |
| ATOM | 754 | CG | LEU | B | 204 | 51.142 | 45.743 | 72.411 | 1.00 | 33.26 | B | C |
| ATOM | 755 | CD1 | LEU | B | 204 | 49.643 | 45.874 | 72.607 | 1.00 | 33.72 | B | C |
| ATOM | 756 | CD2 | LEU | B | 204 | 51.856 | 45.725 | 73.759 | 1.00 | 29.65 | B | C |
| ATOM | 757 | C | LEU | B | 204 | 52.797 | 42.927 | 70.266 | 1.00 | 34.05 | B | C |
| ATOM | 758 | O | LEU | B | 204 | 52.567 | 41.887 | 70.873 | 1.00 | 37.13 | B | O |
| ATOM | 759 | N | GLY | B | 205 | 53.043 | 42.964 | 68.961 | 1.00 | 33.45 | B | N |
| ATOM | 760 | CA | GLY | B | 205 | 53.094 | 41.745 | 68.175 | 1.00 | 30.26 | B | C |
| ATOM | 761 | C | GLY | B | 205 | 51.996 | 40.716 | 68.357 | 1.00 | 29.88 | B | C |
| ATOM | 762 | O | GLY | B | 205 | 52.260 | 39.521 | 68.225 | 1.00 | 30.63 | B | O |
| ATOM | 763 | N | TYR | B | 206 | 50.772 | 41.144 | 68.660 | 1.00 | 29.45 | B | N |
| ATOM | 764 | CA | TYR | B | 206 | 49.664 | 40.191 | 68.813 | 1.00 | 28.78 | B | C |
| ATOM | 765 | CB | TYR | B | 206 | 48.449 | 40.844 | 69.471 | 1.00 | 30.14 | B | C |
| ATOM | 766 | CG | TYR | B | 206 | 48.635 | 41.245 | 70.910 | 1.00 | 35.12 | B | C |
| ATOM | 767 | CD1 | TYR | B | 206 | 49.575 | 40.609 | 71.721 | 1.00 | 37.55 | B | C |
| ATOM | 768 | CE1 | TYR | B | 206 | 49.735 | 40.966 | 73.052 | 1.00 | 37.85 | B | C |
| ATOM | 769 | CD2 | TYR | B | 206 | 47.858 | 42.255 | 71.471 | 1.00 | 36.60 | B | C |
| ATOM | 770 | CE2 | TYR | B | 206 | 48.010 | 42.619 | 72.799 | 1.00 | 37.76 | B | C |
| ATOM | 771 | CZ | TYR | B | 206 | 48.951 | 41.970 | 73.583 | 1.00 | 38.55 | B | C |
| ATOM | 772 | OH | TYR | B | 206 | 49.112 | 42.327 | 74.899 | 1.00 | 40.56 | B | O |
| ATOM | 773 | C | TYR | B | 206 | 49.249 | 39.713 | 67.429 | 1.00 | 29.99 | B | C |
| ATOM | 774 | O | TYR | B | 206 | 49.612 | 40.314 | 66.425 | 1.00 | 30.14 | B | O |
| ATOM | 775 | N | HIS | B | 207 | 48.480 | 38.635 | 67.369 | 1.00 | 30.18 | B | N |
| ATOM | 776 | CA | HIS | B | 207 | 48.026 | 38.130 | 66.088 | 1.00 | 30.65 | B | C |
| ATOM | 777 | CB | HIS | B | 207 | 48.187 | 36.605 | 66.018 | 1.00 | 31.16 | B | C |
| ATOM | 778 | CG | HIS | B | 207 | 47.952 | 36.039 | 64.649 | 1.00 | 35.69 | B | C |
| ATOM | 779 | CD2 | HIS | B | 207 | 48.599 | 36.246 | 63.477 | 1.00 | 38.65 | B | C |
| ATOM | 780 | ND1 | HIS | B | 207 | 46.914 | 35.177 | 64.362 | 1.00 | 40.41 | B | N |
| ATOM | 781 | CE1 | HIS | B | 207 | 46.929 | 34.880 | 63.073 | 1.00 | 37.29 | B | C |
| ATOM | 782 | NE2 | HIS | B | 207 | 47.942 | 35.516 | 62.514 | 1.00 | 39.42 | B | N |
| ATOM | 783 | C | HIS | B | 207 | 46.559 | 38.510 | 65.837 | 1.00 | 30.76 | B | C |
| ATOM | 784 | O | HIS | B | 207 | 45.671 | 38.135 | 66.608 | 1.00 | 27.56 | B | O |
| ATOM | 785 | N | LEU | B | 208 | 46.325 | 39.251 | 64.748 | 1.00 | 31.06 | B | N |
| ATOM | 786 | CA | LEU | B | 208 | 44.990 | 39.699 | 64.344 | 1.00 | 28.26 | B | C |
| ATOM | 787 | CB | LEU | B | 208 | 45.068 | 41.091 | 63.728 | 1.00 | 26.66 | B | C |
| ATOM | 788 | CG | LEU | B | 208 | 45.705 | 42.162 | 64.600 | 1.00 | 24.92 | B | C |
| ATOM | 789 | CD1 | LEU | B | 208 | 45.700 | 43.476 | 63.836 | 1.00 | 26.36 | B | C |
| ATOM | 790 | CD2 | LEU | B | 208 | 44.939 | 42.287 | 65.908 | 1.00 | 22.10 | B | C |
| ATOM | 791 | C | LEU | B | 208 | 44.387 | 38.746 | 63.324 | 1.00 | 27.99 | B | C |
| ATOM | 792 | O | LEU | B | 208 | 45.080 | 38.240 | 62.448 | 1.00 | 30.69 | B | O |
| ATOM | 793 | N | LYS | B | 209 | 43.089 | 38.508 | 63.421 | 1.00 | 27.17 | B | N |
| ATOM | 794 | CA | LYS | B | 209 | 42.449 | 37.597 | 62.497 | 1.00 | 27.74 | B | C |
| ATOM | 795 | CB | LYS | B | 209 | 42.758 | 36.158 | 62.901 | 1.00 | 29.22 | B | C |
| ATOM | 796 | CG | LYS | B | 209 | 42.370 | 35.120 | 61.881 | 1.00 | 28.81 | B | C |
| ATOM | 797 | CD | LYS | B | 209 | 42.741 | 33.735 | 62.382 | 1.00 | 35.03 | B | C |
| ATOM | 798 | CE | LYS | B | 209 | 42.399 | 32.665 | 61.363 | 1.00 | 36.24 | B | C |
| ATOM | 799 | NZ | LYS | B | 209 | 42.033 | 31.384 | 62.031 | 1.00 | 41.31 | B | N |
| ATOM | 800 | C | LYS | B | 209 | 40.951 | 37.815 | 62.465 | 1.00 | 26.99 | B | C |
| ATOM | 801 | O | LYS | B | 209 | 40.302 | 37.914 | 63.499 | 1.00 | 27.66 | B | O |
| ATOM | 802 | N | MET | B | 210 | 40.413 | 37.883 | 61.262 | 1.00 | 24.70 | B | N |
| ATOM | 803 | CA | MET | B | 210 | 38.996 | 38.088 | 61.069 | 1.00 | 28.05 | B | C |
| ATOM | 804 | CB | MET | B | 210 | 38.722 | 38.380 | 59.588 | 1.00 | 27.22 | B | C |
| ATOM | 805 | CG | MET | B | 210 | 37.488 | 39.225 | 59.344 | 1.00 | 36.52 | B | C |
| ATOM | 806 | SD | MET | B | 210 | 37.763 | 41.020 | 59.488 | 1.00 | 33.59 | B | S |
| ATOM | 807 | CE | MET | B | 210 | 39.446 | 41.087 | 59.677 | 1.00 | 23.56 | B | C |
| ATOM | 808 | C | MET | B | 210 | 38.225 | 36.853 | 61.513 | 1.00 | 28.01 | B | C |
| ATOM | 809 | O | MET | B | 210 | 38.647 | 35.726 | 61.252 | 1.00 | 29.44 | B | O |
| ATOM | 810 | N | LYS | B | 211 | 37.103 | 37.065 | 62.193 | 1.00 | 26.40 | B | N |
| ATOM | 811 | CA | LYS | B | 211 | 36.268 | 35.961 | 62.646 | 1.00 | 28.43 | B | C |
| ATOM | 812 | CB | LYS | B | 211 | 36.585 | 35.600 | 64.093 | 1.00 | 32.06 | B | C |
| ATOM | 813 | CG | LYS | B | 211 | 36.064 | 34.231 | 64.496 | 1.00 | 34.63 | B | C |
| ATOM | 814 | CD | LYS | B | 211 | 35.466 | 34.279 | 65.876 | 1.00 | 37.89 | B | C |
| ATOM | 815 | CE | LYS | B | 211 | 36.106 | 33.258 | 66.786 | 1.00 | 38.71 | B | C |
| ATOM | 816 | NZ | LYS | B | 211 | 35.079 | 32.260 | 67.196 | 1.00 | 45.69 | B | N |
| ATOM | 817 | C | LYS | B | 211 | 34.797 | 36.326 | 62.530 | 1.00 | 27.41 | B | C |
| ATOM | 818 | O | LYS | B | 211 | 34.267 | 37.068 | 63.352 | 1.00 | 26.77 | B | O |
| ATOM | 819 | N | ASP | B | 212 | 34.144 | 35.789 | 61.510 | 1.00 | 26.54 | B | N |
| ATOM | 820 | CA | ASP | B | 212 | 32.739 | 36.061 | 61.261 | 1.00 | 25.63 | B | C |
| ATOM | 821 | CB | ASP | B | 212 | 31.879 | 35.404 | 62.334 | 1.00 | 28.37 | B | C |
| ATOM | 822 | CG | ASP | B | 212 | 31.864 | 33.896 | 62.220 | 1.00 | 30.04 | B | C |
| ATOM | 823 | OD1 | ASP | B | 212 | 31.652 | 33.374 | 61.105 | 1.00 | 31.11 | B | O |
| ATOM | 824 | OD2 | ASP | B | 212 | 32.064 | 33.232 | 63.255 | 1.00 | 35.77 | B | O |
| ATOM | 825 | C | ASP | B | 212 | 32.461 | 37.568 | 61.194 | 1.00 | 23.66 | B | C |
| ATOM | 826 | O | ASP | B | 212 | 31.506 | 38.074 | 61.787 | 1.00 | 20.82 | B | O |
| ATOM | 827 | N | GLY | B | 213 | 33.325 | 38.273 | 60.470 | 1.00 | 22.02 | B | N |
| ATOM | 828 | CA | GLY | B | 213 | 33.164 | 39.703 | 60.281 | 1.00 | 23.59 | B | C |
| ATOM | 829 | C | GLY | B | 213 | 33.776 | 40.647 | 61.303 | 1.00 | 24.32 | B | C |
| ATOM | 830 | O | GLY | B | 213 | 33.695 | 41.873 | 61.136 | 1.00 | 23.42 | B | O |
| ATOM | 831 | N | VAL | B | 214 | 34.396 | 40.106 | 62.349 | 1.00 | 21.78 | B | N |
| ATOM | 832 | CA | VAL | B | 214 | 34.988 | 40.949 | 63.380 | 1.00 | 20.81 | B | C |
| ATOM | 833 | CB | VAL | B | 214 | 34.226 | 40.758 | 64.727 | 1.00 | 20.36 | B | C |
| ATOM | 834 | CG1 | VAL | B | 214 | 34.770 | 41.695 | 65.798 | 1.00 | 16.91 | B | C |
| ATOM | 835 | CG2 | VAL | B | 214 | 32.751 | 41.021 | 64.511 | 1.00 | 18.66 | B | C |
| ATOM | 836 | C | VAL | B | 214 | 36.465 | 40.629 | 63.571 | 1.00 | 23.23 | B | C |
| ATOM | 837 | O | VAL | B | 214 | 36.854 | 39.467 | 63.535 | 1.00 | 26.34 | B | O |
| ATOM | 838 | N | VAL | B | 215 | 37.297 | 41.654 | 63.741 | 1.00 | 22.04 | B | N |
| ATOM | 839 | CA | VAL | B | 215 | 38.713 | 41.417 | 63.974 | 1.00 | 21.67 | B | C |
| ATOM | 840 | CB | VAL | B | 215 | 39.555 | 42.702 | 63.790 | 1.00 | 20.74 | B | C |
| ATOM | 841 | CG1 | VAL | B | 215 | 41.025 | 42.402 | 64.070 | 1.00 | 19.11 | B | C |
| ATOM | 842 | CG2 | VAL | B | 215 | 39.383 | 43.252 | 62.384 | 1.00 | 19.80 | B | C |
| ATOM | 843 | C | VAL | B | 215 | 38.913 | 40.910 | 65.421 | 1.00 | 24.55 | B | C |
| ATOM | 844 | O | VAL | B | 215 | 38.511 | 41.569 | 66.385 | 1.00 | 23.17 | B | O |
| ATOM | 845 | N | TYR | B | 216 | 39.516 | 39.731 | 65.567 | 1.00 | 24.63 | B | N |
| ATOM | 846 | CA | TYR | B | 216 | 39.782 | 39.167 | 66.885 | 1.00 | 23.06 | B | C |
| ATOM | 847 | CB | TYR | B | 216 | 39.352 | 37.708 | 66.948 | 1.00 | 20.94 | B | C |
| ATOM | 848 | CG | TYR | B | 216 | 37.922 | 37.539 | 67.381 | 1.00 | 21.18 | B | C |
| ATOM | 849 | CD1 | TYR | B | 216 | 37.595 | 36.803 | 68.509 | 1.00 | 21.21 | B | C |
| ATOM | 850 | CE1 | TYR | B | 216 | 36.278 | 36.646 | 68.905 | 1.00 | 20.59 | B | C |
| ATOM | 851 | CD2 | TYR | B | 216 | 36.887 | 38.119 | 66.656 | 1.00 | 24.73 | B | C |
| ATOM | 852 | CE2 | TYR | B | 216 | 35.561 | 37.970 | 67.046 | 1.00 | 21.83 | B | C |
| ATOM | 853 | CZ | TYR | B | 216 | 35.266 | 37.235 | 68.167 | 1.00 | 20.24 | B | C |
| ATOM | 854 | OH | TYR | B | 216 | 33.957 | 37.103 | 68.550 | 1.00 | 21.30 | B | O |
| ATOM | 855 | C | TYR | B | 216 | 41.266 | 39.271 | 67.187 | 1.00 | 24.47 | B | C |
| ATOM | 856 | O | TYR | B | 216 | 42.100 | 39.149 | 66.298 | 1.00 | 22.20 | B | O |
| ATOM | 857 | N | ILE | B | 217 | 41.589 | 39.510 | 68.451 | 1.00 | 27.66 | B | N |
| ATOM | 858 | CA | ILE | B | 217 | 42.972 | 39.644 | 68.863 | 1.00 | 29.85 | B | C |
| ATOM | 859 | CB | ILE | B | 217 | 43.166 | 40.897 | 69.729 | 1.00 | 30.32 | B | C |
| ATOM | 860 | CG2 | ILE | B | 217 | 44.665 | 41.122 | 69.994 | 1.00 | 27.27 | B | C |
| ATOM | 861 | CG1 | ILE | B | 217 | 42.536 | 42.106 | 69.026 | 1.00 | 29.63 | B | C |
| ATOM | 862 | CD1 | ILE | B | 217 | 41.544 | 42.860 | 69.875 | 1.00 | 30.26 | B | C |
| ATOM | 863 | C | ILE | B | 217 | 43.419 | 38.418 | 69.648 | 1.00 | 32.55 | B | C |
| ATOM | 864 | O | ILE | B | 217 | 42.798 | 38.043 | 70.644 | 1.00 | 30.82 | B | O |
| ATOM | 865 | N | TYR | B | 218 | 44.489 | 37.788 | 69.174 | 1.00 | 35.10 | B | N |
| ATOM | 866 | CA | TYR | B | 218 | 45.032 | 36.604 | 69.818 | 1.00 | 35.08 | B | C |
| ATOM | 867 | CB | TYR | B | 218 | 45.098 | 35.438 | 68.840 | 1.00 | 29.76 | B | C |
| ATOM | 868 | CG | TYR | B | 218 | 43.741 | 35.062 | 68.317 | 1.00 | 27.42 | B | C |
| ATOM | 869 | CD1 | TYR | B | 218 | 42.960 | 34.119 | 68.975 | 1.00 | 26.58 | B | C |
| ATOM | 870 | CE1 | TYR | B | 218 | 41.681 | 33.810 | 68.534 | 1.00 | 26.50 | B | C |
| ATOM | 871 | CD2 | TYR | B | 218 | 43.211 | 35.694 | 67.189 | 1.00 | 29.13 | B | C |
| ATOM | 872 | CE2 | TYR | B | 218 | 41.932 | 35.398 | 66.732 | 1.00 | 28.63 | B | C |
| ATOM | 873 | CZ | TYR | B | 218 | 41.168 | 34.457 | 67.407 | 1.00 | 30.16 | B | C |
| ATOM | 874 | OH | TYR | B | 218 | 39.897 | 34.171 | 66.950 | 1.00 | 25.67 | B | O |
| ATOM | 875 | C | TYR | B | 218 | 46.408 | 36.960 | 70.306 | 1.00 | 40.26 | B | C |
| ATOM | 876 | O | TYR | B | 218 | 47.222 | 37.511 | 69.560 | 1.00 | 38.63 | B | O |
| ATOM | 877 | N | ALA | B | 219 | 46.647 | 36.661 | 71.579 | 1.00 | 47.28 | B | N |
| ATOM | 878 | CA | ALA | B | 219 | 47.921 | 36.957 | 72.221 | 1.00 | 52.70 | B | C |
| ATOM | 879 | CB | ALA | B | 219 | 47.972 | 36.343 | 73.628 | 1.00 | 54.51 | B | C |
| ATOM | 880 | C | ALA | B | 219 | 49.054 | 36.418 | 71.378 | 1.00 | 54.11 | B | C |
| ATOM | 881 | O | ALA | B | 219 | 49.034 | 35.258 | 70.987 | 1.00 | 51.84 | B | O |
| ATOM | 882 | N | ASN | B | 220 | 50.015 | 37.294 | 71.096 | 1.00 | 58.22 | B | N |
| ATOM | 883 | CA | ASN | B | 220 | 51.210 | 36.995 | 70.310 | 1.00 | 61.80 | B | C |
| ATOM | 884 | CB | ASN | B | 220 | 52.459 | 37.444 | 71.092 | 1.00 | 63.24 | B | C |
| ATOM | 885 | CG | ASN | B | 220 | 52.116 | 38.151 | 72.415 | 1.00 | 64.72 | B | C |
| ATOM | 886 | OD1 | ASN | B | 220 | 52.642 | 39.227 | 72.706 | 1.00 | 67.53 | B | O |
| ATOM | 887 | ND2 | ASN | B | 220 | 51.237 | 37.544 | 73.216 | 1.00 | 64.68 | B | N |
| ATOM | 888 | C | ASN | B | 220 | 51.319 | 35.512 | 69.954 | 1.00 | 63.36 | B | C |
| ATOM | 889 | O | ASN | B | 220 | 52.304 | 34.842 | 70.296 | 1.00 | 66.17 | B | O |
| ATOM | 890 | N | GLU | B | 221 | 50.318 | 34.999 | 69.250 | 1.00 | 61.65 | B | N |
| ATOM | 891 | CA | GLU | B | 221 | 50.334 | 33.597 | 68.906 | 1.00 | 60.28 | B | C |
| ATOM | 892 | CB | GLU | B | 221 | 49.849 | 32.768 | 70.087 | 1.00 | 61.89 | B | C |
| ATOM | 893 | CG | GLU | B | 221 | 50.839 | 31.775 | 70.599 | 1.00 | 65.30 | B | C |
| ATOM | 894 | CD | GLU | B | 221 | 50.573 | 31.410 | 72.044 | 1.00 | 70.75 | B | C |
| ATOM | 895 | OE1 | GLU | B | 221 | 49.979 | 30.329 | 72.295 | 1.00 | 72.80 | B | O |
| ATOM | 896 | OE2 | GLU | B | 221 | 50.960 | 32.209 | 72.930 | 1.00 | 73.07 | B | O |
| ATOM | 897 | C | GLU | B | 221 | 49.473 | 33.263 | 67.722 | 1.00 | 59.78 | B | C |
| ATOM | 898 | O | GLU | B | 221 | 48.251 | 33.434 | 67.764 | 1.00 | 58.13 | B | O |
| ATOM | 899 | N | ALA | B | 222 | 50.113 | 32.771 | 66.668 | 1.00 | 58.88 | B | N |
| ATOM | 900 | CA | ALA | B | 222 | 49.382 | 32.337 | 65.496 | 1.00 | 58.40 | B | C |
| ATOM | 901 | CB | ALA | B | 222 | 50.349 | 31.964 | 64.361 | 1.00 | 57.38 | B | C |
| ATOM | 902 | C | ALA | B | 222 | 48.651 | 31.100 | 66.037 | 1.00 | 58.24 | B | C |
| ATOM | 903 | O | ALA | B | 222 | 47.980 | 30.375 | 65.306 | 1.00 | 56.92 | B | O |
| ATOM | 904 | N | ALA | B | 223 | 48.805 | 30.879 | 67.344 | 1.00 | 60.28 | B | N |
| ATOM | 905 | CA | ALA | B | 223 | 48.156 | 29.785 | 68.051 | 1.00 | 62.40 | B | C |
| ATOM | 906 | CB | ALA | B | 223 | 48.665 | 29.710 | 69.467 | 1.00 | 61.42 | B | C |
| ATOM | 907 | C | ALA | B | 223 | 46.659 | 30.088 | 68.051 | 1.00 | 65.27 | B | C |
| ATOM | 908 | O | ALA | B | 223 | 45.883 | 29.470 | 68.786 | 1.00 | 66.41 | B | O |
| ATOM | 909 | N | ALA | B | 224 | 46.278 | 31.073 | 67.234 | 1.00 | 65.54 | B | N |
| ATOM | 910 | CA | ALA | B | 224 | 44.892 | 31.478 | 67.065 | 1.00 | 62.20 | B | C |
| ATOM | 911 | CB | ALA | B | 224 | 44.803 | 32.601 | 66.047 | 1.00 | 58.10 | B | C |
| ATOM | 912 | C | ALA | B | 224 | 44.148 | 30.245 | 66.555 | 1.00 | 63.78 | B | C |
| ATOM | 913 | O | ALA | B | 224 | 42.918 | 30.197 | 66.603 | 1.00 | 65.18 | B | O |
| ATOM | 914 | N | GLY | B | 225 | 44.908 | 29.258 | 66.062 | 1.00 | 63.09 | B | N |
| ATOM | 915 | CA | GLY | B | 225 | 44.329 | 28.017 | 65.566 | 1.00 | 61.43 | B | C |
| ATOM | 916 | C | GLY | B | 225 | 43.317 | 27.517 | 66.575 | 1.00 | 61.76 | B | C |
| ATOM | 917 | O | GLY | B | 225 | 42.221 | 27.079 | 66.225 | 1.00 | 62.41 | B | O |
| ATOM | 918 | N | LYS | B | 226 | 43.702 | 27.567 | 67.844 | 1.00 | 61.99 | B | N |
| ATOM | 919 | CA | LYS | B | 226 | 42.805 | 27.185 | 68.918 | 1.00 | 62.10 | B | C |
| ATOM | 920 | CB | LYS | B | 226 | 43.592 | 26.674 | 70.123 | 1.00 | 62.69 | B | C |
| ATOM | 921 | CG | LYS | B | 226 | 42.841 | 25.638 | 70.953 | 1.00 | 68.05 | B | C |
| ATOM | 922 | CD | LYS | B | 226 | 42.549 | 24.357 | 70.155 | 1.00 | 69.40 | B | C |
| ATOM | 923 | CE | LYS | B | 226 | 42.620 | 23.105 | 71.037 | 1.00 | 68.42 | B | C |
| ATOM | 924 | NZ | LYS | B | 226 | 44.034 | 22.666 | 71.280 | 1.00 | 68.88 | B | N |
| ATOM | 925 | C | LYS | B | 226 | 42.150 | 28.525 | 69.233 | 1.00 | 62.52 | B | C |
| ATOM | 926 | O | LYS | B | 226 | 42.821 | 29.461 | 69.687 | 1.00 | 65.26 | B | O |
| ATOM | 927 | N | ASP | B | 227 | 40.855 | 28.632 | 68.956 | 1.00 | 59.33 | B | N |
| ATOM | 928 | CA | ASP | B | 227 | 40.127 | 29.875 | 69.187 | 1.00 | 55.88 | B | C |
| ATOM | 929 | CB | ASP | B | 227 | 38.656 | 29.689 | 68.833 | 1.00 | 56.48 | B | C |
| ATOM | 930 | CG | ASP | B | 227 | 38.146 | 30.768 | 67.903 | 1.00 | 59.75 | B | C |
| ATOM | 931 | OD1 | ASP | B | 227 | 37.523 | 30.405 | 66.883 | 1.00 | 57.34 | B | O |
| ATOM | 932 | OD2 | ASP | B | 227 | 38.370 | 31.974 | 68.192 | 1.00 | 58.86 | B | O |
| ATOM | 933 | C | ASP | B | 227 | 40.241 | 30.381 | 70.618 | 1.00 | 52.83 | B | C |
| ATOM | 934 | O | ASP | B | 227 | 39.348 | 30.157 | 71.429 | 1.00 | 53.73 | B | O |
| ATOM | 935 | N | GLU | B | 228 | 41.334 | 31.074 | 70.920 | 1.00 | 50.01 | B | N |
| ATOM | 936 | CA | GLU | B | 228 | 41.557 | 31.604 | 72.262 | 1.00 | 47.24 | B | C |
| ATOM | 937 | CB | GLU | B | 228 | 42.581 | 30.738 | 73.005 | 1.00 | 48.19 | B | C |
| ATOM | 938 | CG | GLU | B | 228 | 41.990 | 29.474 | 73.615 | 1.00 | 51.95 | B | C |
| ATOM | 939 | CD | GLU | B | 228 | 42.952 | 28.290 | 73.600 | 1.00 | 53.12 | B | C |
| ATOM | 940 | OE1 | GLU | B | 228 | 44.168 | 28.504 | 73.826 | 1.00 | 52.59 | B | O |
| ATOM | 941 | OE2 | GLU | B | 228 | 42.485 | 27.148 | 73.367 | 1.00 | 52.59 | B | O |
| ATOM | 942 | C | GLU | B | 228 | 42.038 | 33.048 | 72.202 | 1.00 | 42.97 | B | C |
| ATOM | 943 | O | GLU | B | 228 | 43.209 | 33.337 | 72.441 | 1.00 | 44.50 | B | O |
| ATOM | 944 | N | PRO | B | 229 | 41.133 | 33.978 | 71.880 | 1.00 | 39.99 | B | N |
| ATOM | 945 | CD | PRO | B | 229 | 39.710 | 33.759 | 71.573 | 1.00 | 38.82 | B | C |
| ATOM | 946 | CA | PRO | B | 229 | 41.502 | 35.394 | 71.795 | 1.00 | 38.29 | B | C |
| ATOM | 947 | CB | PRO | B | 229 | 40.235 | 36.067 | 71.276 | 1.00 | 37.39 | B | C |
| ATOM | 948 | CG | PRO | B | 229 | 39.133 | 35.136 | 71.653 | 1.00 | 35.42 | B | C |
| ATOM | 949 | C | PRO | B | 229 | 41.918 | 35.953 | 73.138 | 1.00 | 37.34 | B | C |
| ATOM | 950 | O | PRO | B | 229 | 41.617 | 35.364 | 74.167 | 1.00 | 37.53 | B | O |
| ATOM | 951 | N | LYS | B | 230 | 42.610 | 37.087 | 73.126 | 1.00 | 38.28 | B | N |
| ATOM | 952 | CA | LYS | B | 230 | 43.025 | 37.735 | 74.363 | 1.00 | 38.32 | B | C |
| ATOM | 953 | CB | LYS | B | 230 | 43.765 | 39.045 | 74.065 | 1.00 | 39.27 | B | C |
| ATOM | 954 | CG | LYS | B | 230 | 45.260 | 38.906 | 73.851 | 1.00 | 39.80 | B | C |
| ATOM | 955 | CD | LYS | B | 230 | 45.988 | 38.854 | 75.169 | 1.00 | 44.72 | B | C |
| ATOM | 956 | CE | LYS | B | 230 | 47.146 | 39.823 | 75.207 | 1.00 | 47.38 | B | C |
| ATOM | 957 | NZ | LYS | B | 230 | 48.458 | 39.090 | 75.212 | 1.00 | 51.91 | B | N |
| ATOM | 958 | C | LYS | B | 230 | 41.732 | 38.042 | 75.125 | 1.00 | 40.30 | B | C |
| ATOM | 959 | O | LYS | B | 230 | 40.686 | 38.274 | 74.513 | 1.00 | 40.15 | B | O |
| ATOM | 960 | N | PRO | B | 231 | 41.779 | 38.025 | 76.469 | 1.00 | 40.96 | B | N |
| ATOM | 961 | CD | PRO | B | 231 | 42.943 | 37.726 | 77.325 | 1.00 | 41.11 | B | C |
| ATOM | 962 | CA | PRO | B | 231 | 40.577 | 38.314 | 77.262 | 1.00 | 40.51 | B | C |
| ATOM | 963 | CB | PRO | B | 231 | 41.100 | 38.346 | 78.701 | 1.00 | 42.62 | B | C |
| ATOM | 964 | CG | PRO | B | 231 | 42.317 | 37.473 | 78.666 | 1.00 | 41.53 | B | C |
| ATOM | 965 | C | PRO | B | 231 | 39.914 | 39.633 | 76.844 | 1.00 | 38.46 | B | C |
| ATOM | 966 | O | PRO | B | 231 | 40.546 | 40.692 | 76.869 | 1.00 | 36.45 | B | O |
| ATOM | 967 | N | LEU | B | 232 | 38.640 | 39.554 | 76.465 | 1.00 | 37.40 | B | N |
| ATOM | 968 | CA | LEU | B | 232 | 37.885 | 40.726 | 76.013 | 1.00 | 37.18 | B | C |
| ATOM | 969 | CB | LEU | B | 232 | 38.492 | 41.257 | 74.715 | 1.00 | 36.61 | B | C |
| ATOM | 970 | CG | LEU | B | 232 | 38.215 | 42.693 | 74.289 | 1.00 | 37.97 | B | C |
| ATOM | 971 | CD1 | LEU | B | 232 | 39.383 | 43.180 | 73.457 | 1.00 | 38.78 | B | C |
| ATOM | 972 | CD2 | LEU | B | 232 | 36.926 | 42.763 | 73.485 | 1.00 | 38.49 | B | C |
| ATOM | 973 | C | LEU | B | 232 | 36.436 | 40.355 | 75.758 | 1.00 | 35.18 | B | C |
| ATOM | 974 | O | LEU | B | 232 | 36.146 | 39.246 | 75.332 | 1.00 | 34.35 | B | O |
| ATOM | 975 | N | LEU | B | 233 | 35.524 | 41.277 | 76.033 | 1.00 | 36.65 | B | N |
| ATOM | 976 | CA | LEU | B | 233 | 34.101 | 41.028 | 75.788 | 1.00 | 38.10 | B | C |
| ATOM | 977 | CB | LEU | B | 233 | 33.223 | 41.902 | 76.692 | 1.00 | 40.47 | B | C |
| ATOM | 978 | CG | LEU | B | 233 | 33.593 | 43.391 | 76.660 | 1.00 | 47.21 | B | C |
| ATOM | 979 | CD1 | LEU | B | 233 | 32.360 | 44.252 | 77.001 | 1.00 | 46.85 | B | C |
| ATOM | 980 | CD2 | LEU | B | 233 | 34.782 | 43.653 | 77.630 | 1.00 | 45.91 | B | C |
| ATOM | 981 | C | LEU | B | 233 | 33.844 | 41.394 | 74.328 | 1.00 | 36.58 | B | C |
| ATOM | 982 | O | LEU | B | 233 | 33.867 | 42.570 | 73.955 | 1.00 | 36.93 | B | O |
| ATOM | 983 | N | TYR | B | 234 | 33.624 | 40.387 | 73.495 | 1.00 | 32.15 | B | N |
| ATOM | 984 | CA | TYR | B | 234 | 33.378 | 40.645 | 72.085 | 1.00 | 29.19 | B | C |
| ATOM | 985 | CB | TYR | B | 234 | 33.931 | 39.493 | 71.237 | 1.00 | 25.02 | B | C |
| ATOM | 986 | CG | TYR | B | 234 | 35.438 | 39.525 | 71.094 | 1.00 | 25.58 | B | C |
| ATOM | 987 | CD1 | TYR | B | 234 | 36.265 | 38.909 | 72.032 | 1.00 | 26.25 | B | C |
| ATOM | 988 | CE1 | TYR | B | 234 | 37.658 | 38.952 | 71.911 | 1.00 | 27.15 | B | C |
| ATOM | 989 | CD2 | TYR | B | 234 | 36.041 | 40.187 | 70.030 | 1.00 | 25.83 | B | C |
| ATOM | 990 | CE2 | TYR | B | 234 | 37.427 | 40.234 | 69.902 | 1.00 | 25.88 | B | C |
| ATOM | 991 | CZ | TYR | B | 234 | 38.226 | 39.619 | 70.840 | 1.00 | 26.22 | B | C |
| ATOM | 992 | OH | TYR | B | 234 | 39.591 | 39.675 | 70.696 | 1.00 | 28.18 | B | O |
| ATOM | 993 | C | TYR | B | 234 | 31.881 | 40.803 | 71.858 | 1.00 | 28.32 | B | C |
| ATOM | 994 | O | TYR | B | 234 | 31.071 | 40.403 | 72.703 | 1.00 | 27.98 | B | O |
| ATOM | 995 | N | PRO | B | 235 | 31.490 | 41.398 | 70.721 | 1.00 | 25.92 | B | N |
| ATOM | 996 | CD | PRO | B | 235 | 32.334 | 41.919 | 69.630 | 1.00 | 25.51 | B | C |
| ATOM | 997 | CA | PRO | B | 235 | 30.059 | 41.568 | 70.453 | 1.00 | 24.19 | B | C |
| ATOM | 998 | CB | PRO | B | 235 | 30.013 | 42.298 | 69.107 | 1.00 | 24.37 | B | C |
| ATOM | 999 | CG | PRO | B | 235 | 31.407 | 42.793 | 68.866 | 1.00 | 26.37 | B | C |
| ATOM | 1000 | C | PRO | B | 235 | 29.371 | 40.214 | 70.376 | 1.00 | 21.53 | B | C |
| ATOM | 1001 | O | PRO | B | 235 | 29.958 | 39.236 | 69.934 | 1.00 | 22.35 | B | O |
| ATOM | 1002 | N | ASN | B | 236 | 28.122 | 40.163 | 70.807 | 1.00 | 22.37 | B | N |
| ATOM | 1003 | CA | ASN | B | 236 | 27.349 | 38.934 | 70.780 | 1.00 | 22.84 | B | C |
| ATOM | 1004 | CB | ASN | B | 236 | 26.853 | 38.597 | 72.183 | 1.00 | 25.61 | B | C |
| ATOM | 1005 | CG | ASN | B | 236 | 26.087 | 37.297 | 72.230 | 1.00 | 28.81 | B | C |
| ATOM | 1006 | OD1 | ASN | B | 236 | 25.176 | 37.060 | 71.431 | 1.00 | 32.46 | B | O |
| ATOM | 1007 | ND2 | ASN | B | 236 | 26.447 | 36.444 | 73.170 | 1.00 | 34.31 | B | N |
| ATOM | 1008 | C | ASN | B | 236 | 26.168 | 39.158 | 69.854 | 1.00 | 23.74 | B | C |
| ATOM | 1009 | O | ASN | B | 236 | 25.203 | 39.832 | 70.226 | 1.00 | 22.08 | B | O |
| ATOM | 1010 | N | MET | B | 237 | 26.248 | 38.581 | 68.655 | 1.00 | 23.43 | B | N |
| ATOM | 1011 | CA | MET | B | 237 | 25.214 | 38.740 | 67.649 | 1.00 | 24.96 | B | C |
| ATOM | 1012 | CB | MET | B | 237 | 25.645 | 38.102 | 66.336 | 1.00 | 28.70 | B | C |
| ATOM | 1013 | CG | MET | B | 237 | 24.903 | 38.684 | 65.139 | 1.00 | 33.12 | B | C |
| ATOM | 1014 | SD | MET | B | 237 | 25.378 | 37.904 | 63.593 | 1.00 | 39.43 | B | S |
| ATOM | 1015 | CE | MET | B | 237 | 23.978 | 36.830 | 63.332 | 1.00 | 38.46 | B | C |
| ATOM | 1016 | C | MET | B | 237 | 23.850 | 38.210 | 68.020 | 1.00 | 22.57 | B | C |
| ATOM | 1017 | O | MET | B | 237 | 22.836 | 38.794 | 67.662 | 1.00 | 24.52 | B | O |
| ATOM | 1018 | N | GLU | B | 238 | 23.813 | 37.095 | 68.720 | 1.00 | 24.61 | B | N |
| ATOM | 1019 | CA | GLU | B | 238 | 22.534 | 36.534 | 69.131 | 1.00 | 28.18 | B | C |
| ATOM | 1020 | CB | GLU | B | 238 | 22.738 | 35.150 | 69.749 | 1.00 | 34.76 | B | C |
| ATOM | 1021 | CG | GLU | B | 238 | 21.476 | 34.298 | 69.757 | 1.00 | 47.02 | B | C |
| ATOM | 1022 | CD | GLU | B | 238 | 21.553 | 33.123 | 70.732 | 1.00 | 55.01 | B | C |
| ATOM | 1023 | OE1 | GLU | B | 238 | 20.484 | 32.706 | 71.250 | 1.00 | 58.24 | B | O |
| ATOM | 1024 | OE2 | GLU | B | 238 | 22.680 | 32.621 | 70.977 | 1.00 | 58.83 | B | O |
| ATOM | 1025 | C | GLU | B | 238 | 21.846 | 37.467 | 70.140 | 1.00 | 25.40 | B | C |
| ATOM | 1026 | O | GLU | B | 238 | 20.627 | 37.627 | 70.124 | 1.00 | 21.85 | B | O |
| ATOM | 1027 | N | GLU | B | 239 | 22.637 | 38.079 | 71.015 | 1.00 | 21.84 | B | N |
| ATOM | 1028 | CA | GLU | B | 239 | 22.096 | 38.997 | 72.005 | 1.00 | 23.20 | B | C |
| ATOM | 1029 | CB | GLU | B | 239 | 23.182 | 39.361 | 73.029 | 1.00 | 26.60 | B | C |
| ATOM | 1030 | CG | GLU | B | 239 | 22.697 | 40.232 | 74.191 | 1.00 | 32.03 | B | C |
| ATOM | 1031 | CD | GLU | B | 239 | 23.843 | 40.743 | 75.070 | 1.00 | 34.33 | B | C |
| ATOM | 1032 | OE1 | GLU | B | 239 | 23.666 | 41.773 | 75.759 | 1.00 | 35.78 | B | O |
| ATOM | 1033 | OE2 | GLU | B | 239 | 24.923 | 40.114 | 75.071 | 1.00 | 38.61 | B | O |
| ATOM | 1034 | C | GLU | B | 239 | 21.612 | 40.257 | 71.285 | 1.00 | 19.73 | B | C |
| ATOM | 1035 | O | GLU | B | 239 | 20.557 | 40.812 | 71.594 | 1.00 | 18.95 | B | O |
| ATOM | 1036 | N | PHE | B | 240 | 22.395 | 40.701 | 70.310 | 1.00 | 18.32 | B | N |
| ATOM | 1037 | CA | PHE | B | 240 | 22.051 | 41.895 | 69.548 | 1.00 | 17.56 | B | C |
| ATOM | 1038 | CB | PHE | B | 240 | 23.153 | 42.222 | 68.550 | 1.00 | 14.88 | B | C |
| ATOM | 1039 | CG | PHE | B | 240 | 22.869 | 43.434 | 67.729 | 1.00 | 16.71 | B | C |
| ATOM | 1040 | CD1 | PHE | B | 240 | 22.033 | 43.359 | 66.629 | 1.00 | 17.41 | B | C |
| ATOM | 1041 | CD2 | PHE | B | 240 | 23.449 | 44.653 | 68.047 | 1.00 | 16.75 | B | C |
| ATOM | 1042 | CE1 | PHE | B | 240 | 21.780 | 44.479 | 65.854 | 1.00 | 17.15 | B | C |
| ATOM | 1043 | CE2 | PHE | B | 240 | 23.203 | 45.774 | 67.281 | 1.00 | 17.48 | B | C |
| ATOM | 1044 | CZ | PHE | B | 240 | 22.364 | 45.685 | 66.178 | 1.00 | 16.66 | B | C |
| ATOM | 1045 | C | PHE | B | 240 | 20.741 | 41.705 | 68.802 | 1.00 | 18.90 | B | C |
| ATOM | 1046 | O | PHE | B | 240 | 19.871 | 42.581 | 68.810 | 1.00 | 15.74 | B | O |
| ATOM | 1047 | N | LEU | B | 241 | 20.608 | 40.552 | 68.155 | 1.00 | 18.39 | B | N |
| ATOM | 1048 | CA | LEU | B | 241 | 19.406 | 40.248 | 67.404 | 1.00 | 19.63 | B | C |
| ATOM | 1049 | CB | LEU | B | 241 | 19.611 | 38.960 | 66.599 | 1.00 | 18.53 | B | C |
| ATOM | 1050 | CG | LEU | B | 241 | 20.471 | 39.072 | 65.325 | 1.00 | 22.75 | B | C |
| ATOM | 1051 | CD1 | LEU | B | 241 | 20.858 | 37.663 | 64.821 | 1.00 | 19.60 | B | C |
| ATOM | 1052 | CD2 | LEU | B | 241 | 19.702 | 39.840 | 64.241 | 1.00 | 17.74 | B | C |
| ATOM | 1053 | C | LEU | B | 241 | 18.189 | 40.118 | 68.322 | 1.00 | 21.17 | B | C |
| ATOM | 1054 | O | LEU | B | 241 | 17.062 | 40.396 | 67.915 | 1.00 | 19.71 | B | O |
| ATOM | 1055 | N | ASP | B | 242 | 18.410 | 39.694 | 69.563 | 1.00 | 23.18 | B | N |
| ATOM | 1056 | CA | ASP | B | 242 | 17.304 | 39.549 | 70.512 | 1.00 | 23.77 | B | C |
| ATOM | 1057 | CB | ASP | B | 242 | 17.776 | 38.866 | 71.796 | 1.00 | 28.78 | B | C |
| ATOM | 1058 | CG | ASP | B | 242 | 17.999 | 37.379 | 71.622 | 1.00 | 37.27 | B | C |
| ATOM | 1059 | OD1 | ASP | B | 242 | 17.480 | 36.800 | 70.639 | 1.00 | 44.82 | B | O |
| ATOM | 1060 | OD2 | ASP | B | 242 | 18.698 | 36.780 | 72.471 | 1.00 | 42.17 | B | O |
| ATOM | 1061 | C | ASP | B | 242 | 16.770 | 40.932 | 70.863 | 1.00 | 21.84 | B | C |
| ATOM | 1062 | O | ASP | B | 242 | 15.562 | 41.157 | 70.917 | 1.00 | 19.74 | B | O |
| ATOM | 1063 | N | ASP | B | 243 | 17.697 | 41.848 | 71.117 | 1.00 | 19.52 | B | N |
| ATOM | 1064 | CA | ASP | B | 243 | 17.361 | 43.217 | 71.464 | 1.00 | 18.39 | B | C |
| ATOM | 1065 | CB | ASP | B | 243 | 18.621 | 43.945 | 71.934 | 1.00 | 16.45 | B | C |
| ATOM | 1066 | CG | ASP | B | 243 | 19.139 | 43.407 | 73.262 | 1.00 | 17.28 | B | C |
| ATOM | 1067 | OD1 | ASP | B | 243 | 18.320 | 42.875 | 74.036 | 1.00 | 17.86 | B | O |
| ATOM | 1068 | OD2 | ASP | B | 243 | 20.353 | 43.511 | 73.535 | 1.00 | 17.18 | B | O |
| ATOM | 1069 | C | ASP | B | 243 | 16.746 | 43.941 | 70.278 | 1.00 | 17.47 | B | C |
| ATOM | 1070 | O | ASP | B | 243 | 15.821 | 44.720 | 70.446 | 1.00 | 17.83 | B | O |
| ATOM | 1071 | N | MET | B | 244 | 17.263 | 43.675 | 69.081 | 1.00 | 18.00 | B | N |
| ATOM | 1072 | CA | MET | B | 244 | 16.761 | 44.310 | 67.874 | 1.00 | 18.04 | B | C |
| ATOM | 1073 | CB | MET | B | 244 | 17.633 | 43.915 | 66.679 | 1.00 | 17.88 | B | C |
| ATOM | 1074 | CG | MET | B | 244 | 17.190 | 44.497 | 65.356 | 1.00 | 18.69 | B | C |
| ATOM | 1075 | SD | MET | B | 244 | 17.987 | 43.623 | 63.984 | 1.00 | 27.24 | B | S |
| ATOM | 1076 | CE | MET | B | 244 | 16.935 | 42.146 | 63.836 | 1.00 | 18.62 | B | C |
| ATOM | 1077 | C | MET | B | 244 | 15.314 | 43.889 | 67.647 | 1.00 | 18.11 | B | C |
| ATOM | 1078 | O | MET | B | 244 | 14.445 | 44.727 | 67.410 | 1.00 | 18.70 | B | O |
| ATOM | 1079 | N | ASN | B | 245 | 15.048 | 42.590 | 67.747 | 1.00 | 16.70 | B | N |
| ATOM | 1080 | CA | ASN | B | 245 | 13.697 | 42.077 | 67.543 | 1.00 | 18.47 | B | C |
| ATOM | 1081 | CB | ASN | B | 245 | 13.693 | 40.557 | 67.635 | 1.00 | 18.35 | B | C |
| ATOM | 1082 | CG | ASN | B | 245 | 14.281 | 39.907 | 66.401 | 1.00 | 22.78 | B | C |
| ATOM | 1083 | OD1 | ASN | B | 245 | 13.943 | 40.274 | 65.280 | 1.00 | 25.57 | B | O |
| ATOM | 1084 | ND2 | ASN | B | 245 | 15.171 | 38.949 | 66.600 | 1.00 | 23.34 | B | N |
| ATOM | 1085 | C | ASN | B | 245 | 12.722 | 42.651 | 68.555 | 1.00 | 20.39 | B | C |
| ATOM | 1086 | O | ASN | B | 245 | 11.550 | 42.880 | 68.255 | 1.00 | 22.01 | B | O |
| ATOM | 1087 | N | PHE | B | 246 | 13.206 | 42.882 | 69.769 | 1.00 | 21.81 | B | N |
| ATOM | 1088 | CA | PHE | B | 246 | 12.358 | 43.447 | 70.812 | 1.00 | 19.89 | B | C |
| ATOM | 1089 | CB | PHE | B | 246 | 13.088 | 43.447 | 72.151 | 1.00 | 18.60 | B | C |
| ATOM | 1090 | CG | PHE | B | 246 | 12.532 | 44.441 | 73.121 | 1.00 | 22.59 | B | C |
| ATOM | 1091 | CD1 | PHE | B | 246 | 13.097 | 45.707 | 73.246 | 1.00 | 23.90 | B | C |
| ATOM | 1092 | CD2 | PHE | B | 246 | 11.403 | 44.137 | 73.866 | 1.00 | 22.13 | B | C |
| ATOM | 1093 | CE1 | PHE | B | 246 | 12.541 | 46.654 | 74.093 | 1.00 | 23.49 | B | C |
| ATOM | 1094 | CE2 | PHE | B | 246 | 10.841 | 45.078 | 74.716 | 1.00 | 21.44 | B | C |
| ATOM | 1095 | CZ | PHE | B | 246 | 11.410 | 46.339 | 74.828 | 1.00 | 21.33 | B | C |
| ATOM | 1096 | C | PHE | B | 246 | 11.977 | 44.888 | 70.444 | 1.00 | 17.86 | B | C |
| ATOM | 1097 | O | PHE | B | 246 | 10.832 | 45.301 | 70.608 | 1.00 | 16.98 | B | O |
| ATOM | 1098 | N | LEU | B | 247 | 12.948 | 45.643 | 69.945 | 1.00 | 14.61 | B | N |
| ATOM | 1099 | CA | LEU | B | 247 | 12.699 | 47.024 | 69.572 | 1.00 | 14.92 | B | C |
| ATOM | 1100 | CB | LEU | B | 247 | 14.025 | 47.734 | 69.279 | 1.00 | 10.21 | B | C |
| ATOM | 1101 | CG | LEU | B | 247 | 14.870 | 48.074 | 70.521 | 1.00 | 13.36 | B | C |
| ATOM | 1102 | CD1 | LEU | B | 247 | 16.228 | 48.574 | 70.072 | 1.00 | 11.59 | B | C |
| ATOM | 1103 | CD2 | LEU | B | 247 | 14.171 | 49.134 | 71.395 | 1.00 | 6.31 | B | C |
| ATOM | 1104 | C | LEU | B | 247 | 11.768 | 47.085 | 68.367 | 1.00 | 15.84 | B | C |
| ATOM | 1105 | O | LEU | B | 247 | 10.888 | 47.947 | 68.286 | 1.00 | 15.13 | B | O |
| ATOM | 1106 | N | LEU | B | 248 | 11.954 | 46.152 | 67.440 | 1.00 | 17.12 | B | N |
| ATOM | 1107 | CA | LEU | B | 248 | 11.114 | 46.111 | 66.260 | 1.00 | 18.72 | B | C |
| ATOM | 1108 | CB | LEU | B | 248 | 11.541 | 44.960 | 65.347 | 1.00 | 20.98 | B | C |
| ATOM | 1109 | CG | LEU | B | 248 | 12.212 | 45.307 | 64.015 | 1.00 | 24.01 | B | C |
| ATOM | 1110 | CD1 | LEU | B | 248 | 12.797 | 46.711 | 64.037 | 1.00 | 28.87 | B | C |
| ATOM | 1111 | CD2 | LEU | B | 248 | 13.302 | 44.295 | 63.752 | 1.00 | 23.77 | B | C |
| ATOM | 1112 | C | LEU | B | 248 | 9.681 | 45.917 | 66.727 | 1.00 | 20.47 | B | C |
| ATOM | 1113 | O | LEU | B | 248 | 8.763 | 46.623 | 66.291 | 1.00 | 21.62 | B | O |
| ATOM | 1114 | N | ALA | B | 249 | 9.483 | 44.976 | 67.642 | 1.00 | 19.58 | B | N |
| ATOM | 1115 | CA | ALA | B | 249 | 8.138 | 44.721 | 68.134 | 1.00 | 20.91 | B | C |
| ATOM | 1116 | CB | ALA | B | 249 | 8.148 | 43.526 | 69.074 | 1.00 | 19.69 | B | C |
| ATOM | 1117 | C | ALA | B | 249 | 7.603 | 45.953 | 68.851 | 1.00 | 21.11 | B | C |
| ATOM | 1118 | O | ALA | B | 249 | 6.490 | 46.414 | 68.586 | 1.00 | 25.37 | B | O |
| ATOM | 1119 | N | LEU | B | 250 | 8.416 | 46.500 | 69.743 | 1.00 | 20.49 | B | N |
| ATOM | 1120 | CA | LEU | B | 250 | 8.028 | 47.673 | 70.520 | 1.00 | 18.63 | B | C |
| ATOM | 1121 | CB | LEU | B | 250 | 9.209 | 48.139 | 71.382 | 1.00 | 16.80 | B | C |
| ATOM | 1122 | CG | LEU | B | 250 | 8.922 | 49.365 | 72.246 | 1.00 | 14.96 | B | C |
| ATOM | 1123 | CD1 | LEU | B | 250 | 8.093 | 48.896 | 73.398 | 1.00 | 14.52 | B | C |
| ATOM | 1124 | CD2 | LEU | B | 250 | 10.195 | 50.037 | 72.735 | 1.00 | 12.68 | B | C |
| ATOM | 1125 | C | LEU | B | 250 | 7.504 | 48.846 | 69.687 | 1.00 | 19.96 | B | C |
| ATOM | 1126 | O | LEU | B | 250 | 6.396 | 49.339 | 69.936 | 1.00 | 17.34 | B | O |
| ATOM | 1127 | N | ILE | B | 251 | 8.283 | 49.293 | 68.700 | 1.00 | 20.79 | B | N |
| ATOM | 1128 | CA | ILE | B | 251 | 7.856 | 50.432 | 67.889 | 1.00 | 21.73 | B | C |
| ATOM | 1129 | CB | ILE | B | 251 | 8.988 | 50.923 | 66.936 | 1.00 | 21.06 | B | C |
| ATOM | 1130 | CG2 | ILE | B | 251 | 10.274 | 51.108 | 67.720 | 1.00 | 19.13 | B | C |
| ATOM | 1131 | CG1 | ILE | B | 251 | 9.205 | 49.936 | 65.795 | 1.00 | 21.36 | B | C |
| ATOM | 1132 | CD1 | ILE | B | 251 | 10.356 | 50.323 | 64.876 | 1.00 | 21.24 | B | C |
| ATOM | 1133 | C | ILE | B | 251 | 6.575 | 50.192 | 67.093 | 1.00 | 21.15 | B | C |
| ATOM | 1134 | O | ILE | B | 251 | 5.948 | 51.139 | 66.617 | 1.00 | 24.37 | B | O |
| ATOM | 1135 | N | ALA | B | 252 | 6.164 | 48.938 | 66.970 | 1.00 | 20.52 | B | N |
| ATOM | 1136 | CA | ALA | B | 252 | 4.948 | 48.640 | 66.232 | 1.00 | 22.46 | B | C |
| ATOM | 1137 | CB | ALA | B | 252 | 5.155 | 47.418 | 65.352 | 1.00 | 21.90 | B | C |
| ATOM | 1138 | C | ALA | B | 252 | 3.751 | 48.421 | 67.152 | 1.00 | 23.23 | B | C |
| ATOM | 1139 | O | ALA | B | 252 | 2.629 | 48.263 | 66.680 | 1.00 | 24.93 | B | O |
| ATOM | 1140 | N | GLN | B | 253 | 3.993 | 48.423 | 68.461 | 1.00 | 23.05 | B | N |
| ATOM | 1141 | CA | GLN | B | 253 | 2.942 | 48.221 | 69.463 | 1.00 | 23.74 | B | C |
| ATOM | 1142 | CB | GLN | B | 253 | 3.572 | 47.997 | 70.816 | 1.00 | 28.14 | B | C |
| ATOM | 1143 | CG | GLN | B | 253 | 3.286 | 46.665 | 71.403 | 1.00 | 32.16 | B | C |
| ATOM | 1144 | CD | GLN | B | 253 | 4.257 | 46.357 | 72.502 | 1.00 | 35.11 | B | C |
| ATOM | 1145 | OE1 | GLN | B | 253 | 5.030 | 45.412 | 72.410 | 1.00 | 41.32 | B | O |
| ATOM | 1146 | NE2 | GLN | B | 253 | 4.234 | 47.163 | 73.554 | 1.00 | 38.74 | B | N |
| ATOM | 1147 | C | GLN | B | 253 | 1.944 | 49.367 | 69.599 | 1.00 | 22.41 | B | C |
| ATOM | 1148 | O | GLN | B | 253 | 2.310 | 50.489 | 69.935 | 1.00 | 22.11 | B | O |
| ATOM | 1149 | N | GLY | B | 254 | 0.672 | 49.054 | 69.398 | 1.00 | 21.23 | B | N |
| ATOM | 1150 | CA | GLY | B | 254 | −0.367 | 50.065 | 69.446 | 1.00 | 19.86 | B | C |
| ATOM | 1151 | C | GLY | B | 254 | −0.328 | 51.004 | 70.622 | 1.00 | 19.64 | B | C |
| ATOM | 1152 | O | GLY | B | 254 | −0.258 | 52.220 | 70.464 | 1.00 | 21.84 | B | O |
| ATOM | 1153 | N | PRO | B | 255 | −0.402 | 50.463 | 71.836 | 1.00 | 20.91 | B | N |
| ATOM | 1154 | CD | PRO | B | 255 | −0.547 | 49.026 | 72.138 | 1.00 | 20.34 | B | C |
| ATOM | 1155 | CA | PRO | B | 255 | −0.375 | 51.284 | 73.051 | 1.00 | 16.62 | B | C |
| ATOM | 1156 | CB | PRO | B | 255 | −0.479 | 50.261 | 74.171 | 1.00 | 17.46 | B | C |
| ATOM | 1157 | CG | PRO | B | 255 | −1.121 | 49.048 | 73.514 | 1.00 | 20.18 | B | C |
| ATOM | 1158 | C | PRO | B | 255 | 0.870 | 52.156 | 73.178 | 1.00 | 14.98 | B | C |
| ATOM | 1159 | O | PRO | B | 255 | 0.790 | 53.287 | 73.633 | 1.00 | 15.15 | B | O |
| ATOM | 1160 | N | VAL | B | 256 | 2.025 | 51.632 | 72.789 | 1.00 | 14.07 | B | N |
| ATOM | 1161 | CA | VAL | B | 256 | 3.250 | 52.412 | 72.870 | 1.00 | 14.17 | B | C |
| ATOM | 1162 | CB | VAL | B | 256 | 4.497 | 51.519 | 72.611 | 1.00 | 13.30 | B | C |
| ATOM | 1163 | CG1 | VAL | B | 256 | 5.766 | 52.316 | 72.836 | 1.00 | 10.87 | B | C |
| ATOM | 1164 | CG2 | VAL | B | 256 | 4.483 | 50.323 | 73.555 | 1.00 | 11.43 | B | C |
| ATOM | 1165 | C | VAL | B | 256 | 3.203 | 53.583 | 71.869 | 1.00 | 16.22 | B | C |
| ATOM | 1166 | O | VAL | B | 256 | 3.637 | 54.699 | 72.175 | 1.00 | 14.67 | B | O |
| ATOM | 1167 | N | LYS | B | 257 | 2.653 | 53.325 | 70.687 | 1.00 | 15.56 | B | N |
| ATOM | 1168 | CA | LYS | B | 257 | 2.533 | 54.346 | 69.658 | 1.00 | 17.59 | B | C |
| ATOM | 1169 | CB | LYS | B | 257 | 1.994 | 53.716 | 68.360 | 1.00 | 17.67 | B | C |
| ATOM | 1170 | CG | LYS | B | 257 | 3.084 | 53.347 | 67.376 | 1.00 | 23.15 | B | C |
| ATOM | 1171 | CD | LYS | B | 257 | 2.821 | 52.021 | 66.743 | 1.00 | 24.91 | B | C |
| ATOM | 1172 | CE | LYS | B | 257 | 2.132 | 52.184 | 65.412 | 1.00 | 29.95 | B | C |
| ATOM | 1173 | NZ | LYS | B | 257 | 1.403 | 50.908 | 65.045 | 1.00 | 37.98 | B | N |
| ATOM | 1174 | C | LYS | B | 257 | 1.589 | 55.443 | 70.154 | 1.00 | 16.72 | B | C |
| ATOM | 1175 | O | LYS | B | 257 | 1.869 | 56.645 | 70.028 | 1.00 | 14.83 | B | O |
| ATOM | 1176 | N | THR | B | 258 | 0.466 | 55.026 | 70.726 | 1.00 | 14.74 | B | N |
| ATOM | 1177 | CA | THR | B | 258 | −0.518 | 55.975 | 71.233 | 1.00 | 15.78 | B | C |
| ATOM | 1178 | CB | THR | B | 258 | −1.731 | 55.235 | 71.821 | 1.00 | 17.52 | B | C |
| ATOM | 1179 | OG1 | THR | B | 258 | −2.389 | 54.505 | 70.787 | 1.00 | 21.92 | B | O |
| ATOM | 1180 | CG2 | THR | B | 258 | −2.710 | 56.207 | 72.443 | 1.00 | 17.47 | B | C |
| ATOM | 1181 | C | THR | B | 258 | 0.079 | 56.868 | 72.332 | 1.00 | 16.63 | B | C |
| ATOM | 1182 | O | THR | B | 258 | −0.076 | 58.086 | 72.309 | 1.00 | 16.85 | B | O |
| ATOM | 1183 | N | TYR | B | 259 | 0.753 | 56.252 | 73.299 | 1.00 | 15.35 | B | N |
| ATOM | 1184 | CA | TYR | B | 259 | 1.345 | 56.985 | 74.411 | 1.00 | 13.79 | B | C |
| ATOM | 1185 | CB | TYR | B | 259 | 1.982 | 56.013 | 75.418 | 1.00 | 14.27 | B | C |
| ATOM | 1186 | CG | TYR | B | 259 | 2.650 | 56.705 | 76.595 | 1.00 | 17.23 | B | C |
| ATOM | 1187 | CD1 | TYR | B | 259 | 4.039 | 56.847 | 76.650 | 1.00 | 16.94 | B | C |
| ATOM | 1188 | CE1 | TYR | B | 259 | 4.659 | 57.494 | 77.731 | 1.00 | 19.45 | B | C |
| ATOM | 1189 | CD2 | TYR | B | 259 | 1.888 | 57.228 | 77.655 | 1.00 | 17.03 | B | C |
| ATOM | 1190 | CE2 | TYR | B | 259 | 2.497 | 57.878 | 78.740 | 1.00 | 15.09 | B | C |
| ATOM | 1191 | CZ | TYR | B | 259 | 3.881 | 58.011 | 78.776 | 1.00 | 19.31 | B | C |
| ATOM | 1192 | OH | TYR | B | 259 | 4.494 | 58.671 | 79.832 | 1.00 | 18.32 | B | O |
| ATOM | 1193 | C | TYR | B | 259 | 2.392 | 57.967 | 73.949 | 1.00 | 13.03 | B | C |
| ATOM | 1194 | O | TYR | B | 259 | 2.308 | 59.169 | 74.247 | 1.00 | 13.44 | B | O |
| ATOM | 1195 | N | THR | B | 260 | 3.393 | 57.462 | 73.232 | 1.00 | 13.54 | B | N |
| ATOM | 1196 | CA | THR | B | 260 | 4.465 | 58.329 | 72.749 | 1.00 | 13.84 | B | C |
| ATOM | 1197 | CB | THR | B | 260 | 5.554 | 57.498 | 72.039 | 1.00 | 15.51 | B | C |
| ATOM | 1198 | OG1 | THR | B | 260 | 4.993 | 56.797 | 70.915 | 1.00 | 12.29 | B | O |
| ATOM | 1199 | CG2 | THR | B | 260 | 6.148 | 56.498 | 73.025 | 1.00 | 10.48 | B | C |
| ATOM | 1200 | C | THR | B | 260 | 3.964 | 59.463 | 71.838 | 1.00 | 12.84 | B | C |
| ATOM | 1201 | O | THR | B | 260 | 4.485 | 60.572 | 71.877 | 1.00 | 14.68 | B | O |
| ATOM | 1202 | N | HIS | B | 261 | 2.954 | 59.191 | 71.020 | 1.00 | 14.71 | B | N |
| ATOM | 1203 | CA | HIS | B | 261 | 2.403 | 60.220 | 70.143 | 1.00 | 15.62 | B | C |
| ATOM | 1204 | CB | HIS | B | 261 | 1.287 | 59.625 | 69.263 | 1.00 | 20.73 | B | C |
| ATOM | 1205 | CG | HIS | B | 261 | 0.697 | 60.593 | 68.276 | 1.00 | 23.02 | B | C |
| ATOM | 1206 | CD2 | HIS | B | 261 | 1.197 | 61.122 | 67.134 | 1.00 | 21.80 | B | C |
| ATOM | 1207 | ND1 | HIS | B | 261 | −0.577 | 61.111 | 68.408 | 1.00 | 24.83 | B | N |
| ATOM | 1208 | CE1 | HIS | B | 261 | −0.837 | 61.914 | 67.392 | 1.00 | 18.74 | B | C |
| ATOM | 1209 | NE2 | HIS | B | 261 | 0.223 | 61.938 | 66.606 | 1.00 | 25.30 | B | N |
| ATOM | 1210 | C | HIS | B | 261 | 1.842 | 61.369 | 70.989 | 1.00 | 14.91 | B | C |
| ATOM | 1211 | O | HIS | B | 261 | 2.057 | 62.544 | 70.692 | 1.00 | 14.53 | B | O |
| ATOM | 1212 | N | ARG | B | 262 | 1.108 | 61.020 | 72.040 | 1.00 | 14.98 | B | N |
| ATOM | 1213 | CA | ARG | B | 262 | 0.520 | 62.019 | 72.928 | 1.00 | 13.72 | B | C |
| ATOM | 1214 | CB | ARG | B | 262 | −0.386 | 61.319 | 73.942 | 1.00 | 17.09 | B | C |
| ATOM | 1215 | CG | ARG | B | 262 | −1.485 | 62.217 | 74.509 | 1.00 | 29.61 | B | C |
| ATOM | 1216 | CD | ARG | B | 262 | −2.187 | 61.579 | 75.721 | 1.00 | 34.80 | B | C |
| ATOM | 1217 | NE | ARG | B | 262 | −2.597 | 60.193 | 75.464 | 1.00 | 41.60 | B | N |
| ATOM | 1218 | CZ | ARG | B | 262 | −2.064 | 59.132 | 76.067 | 1.00 | 41.50 | B | C |
| ATOM | 1219 | NH1 | ARG | B | 262 | −1.097 | 59.297 | 76.963 | 1.00 | 41.81 | B | N |
| ATOM | 1220 | NH2 | ARG | B | 262 | −2.489 | 57.907 | 75.777 | 1.00 | 41.95 | B | N |
| ATOM | 1221 | C | ARG | B | 262 | 1.613 | 62.852 | 73.645 | 1.00 | 11.81 | B | C |
| ATOM | 1222 | O | ARG | B | 262 | 1.549 | 64.085 | 73.682 | 1.00 | 10.97 | B | O |
| ATOM | 1223 | N | ARG | B | 263 | 2.633 | 62.186 | 74.180 | 1.00 | 8.73 | B | N |
| ATOM | 1224 | CA | ARG | B | 263 | 3.712 | 62.887 | 74.858 | 1.00 | 8.89 | B | C |
| ATOM | 1225 | CB | ARG | B | 263 | 4.711 | 61.869 | 75.434 | 1.00 | 10.62 | B | C |
| ATOM | 1226 | CG | ARG | B | 263 | 4.136 | 60.894 | 76.526 | 1.00 | 10.39 | B | C |
| ATOM | 1227 | CD | ARG | B | 263 | 3.238 | 61.574 | 77.581 | 1.00 | 6.46 | B | C |
| ATOM | 1228 | NE | ARG | B | 263 | 3.876 | 62.730 | 78.213 | 1.00 | 6.92 | B | N |
| ATOM | 1229 | CZ | ARG | B | 263 | 3.211 | 63.684 | 78.859 | 1.00 | 9.40 | B | C |
| ATOM | 1230 | NH1 | ARG | B | 263 | 1.894 | 63.610 | 78.962 | 1.00 | 6.82 | B | N |
| ATOM | 1231 | NH2 | ARG | B | 263 | 3.851 | 64.739 | 79.357 | 1.00 | 8.07 | B | N |
| ATOM | 1232 | C | ARG | B | 263 | 4.436 | 63.875 | 73.932 | 1.00 | 10.87 | B | C |
| ATOM | 1233 | O | ARG | B | 263 | 4.802 | 64.984 | 74.347 | 1.00 | 12.25 | B | O |
| ATOM | 1234 | N | LEU | B | 264 | 4.637 | 63.488 | 72.671 | 1.00 | 12.91 | B | N |
| ATOM | 1235 | CA | LEU | B | 264 | 5.310 | 64.367 | 71.705 | 1.00 | 11.42 | B | C |
| ATOM | 1236 | CB | LEU | B | 264 | 5.598 | 63.613 | 70.390 | 1.00 | 10.20 | B | C |
| ATOM | 1237 | CG | LEU | B | 264 | 6.703 | 62.545 | 70.486 | 1.00 | 9.76 | B | C |
| ATOM | 1238 | CD1 | LEU | B | 264 | 6.613 | 61.540 | 69.356 | 1.00 | 7.76 | B | C |
| ATOM | 1239 | CD2 | LEU | B | 264 | 8.052 | 63.232 | 70.493 | 1.00 | 8.24 | B | C |
| ATOM | 1240 | C | LEU | B | 264 | 4.448 | 65.602 | 71.443 | 1.00 | 11.94 | B | C |
| ATOM | 1241 | O | LEU | B | 264 | 4.960 | 66.717 | 71.336 | 1.00 | 12.91 | B | O |
| ATOM | 1242 | N | LYS | B | 265 | 3.137 | 65.407 | 71.352 | 1.00 | 12.97 | B | N |
| ATOM | 1243 | CA | LYS | B | 265 | 2.225 | 66.528 | 71.134 | 1.00 | 13.42 | B | C |
| ATOM | 1244 | CB | LYS | B | 265 | 0.784 | 66.029 | 70.994 | 1.00 | 13.38 | B | C |
| ATOM | 1245 | CG | LYS | B | 265 | 0.421 | 65.529 | 69.599 | 1.00 | 22.52 | B | C |
| ATOM | 1246 | CD | LYS | B | 265 | −0.845 | 64.646 | 69.612 | 1.00 | 26.29 | B | C |
| ATOM | 1247 | CE | LYS | B | 265 | −2.116 | 65.430 | 70.006 | 1.00 | 29.29 | B | C |
| ATOM | 1248 | NZ | LYS | B | 265 | −3.327 | 64.549 | 70.221 | 1.00 | 32.88 | B | N |
| ATOM | 1249 | C | LYS | B | 265 | 2.324 | 67.456 | 72.338 | 1.00 | 12.33 | B | C |
| ATOM | 1250 | O | LYS | B | 265 | 2.322 | 68.680 | 72.196 | 1.00 | 12.85 | B | O |
| ATOM | 1251 | N | PHE | B | 266 | 2.413 | 66.874 | 73.532 | 1.00 | 12.30 | B | N |
| ATOM | 1252 | CA | PHE | B | 266 | 2.516 | 67.699 | 74.734 | 1.00 | 11.68 | B | C |
| ATOM | 1253 | CB | PHE | B | 266 | 2.438 | 66.833 | 76.004 | 1.00 | 13.22 | B | C |
| ATOM | 1254 | CG | PHE | B | 266 | 2.622 | 67.626 | 77.289 | 1.00 | 15.01 | B | C |
| ATOM | 1255 | CD1 | PHE | B | 266 | 1.578 | 68.396 | 77.801 | 1.00 | 11.85 | B | C |
| ATOM | 1256 | CD2 | PHE | B | 266 | 3.860 | 67.656 | 77.941 | 1.00 | 14.02 | B | C |
| ATOM | 1257 | CE1 | PHE | B | 266 | 1.760 | 69.190 | 78.934 | 1.00 | 11.78 | B | C |
| ATOM | 1258 | CE2 | PHE | B | 266 | 4.049 | 68.452 | 79.081 | 1.00 | 17.23 | B | C |
| ATOM | 1259 | CZ | PHE | B | 266 | 2.994 | 69.221 | 79.576 | 1.00 | 11.34 | B | C |
| ATOM | 1260 | C | PHE | B | 266 | 3.818 | 68.492 | 74.719 | 1.00 | 9.33 | B | C |
| ATOM | 1261 | O | PHE | B | 266 | 3.833 | 69.688 | 74.991 | 1.00 | 12.92 | B | O |
| ATOM | 1262 | N | LEU | B | 267 | 4.915 | 67.825 | 74.395 | 1.00 | 10.12 | B | N |
| ATOM | 1263 | CA | LEU | B | 267 | 6.218 | 68.481 | 74.341 | 1.00 | 10.07 | B | C |
| ATOM | 1264 | CB | LEU | B | 267 | 7.256 | 67.505 | 73.803 | 1.00 | 11.29 | B | C |
| ATOM | 1265 | CG | LEU | B | 267 | 8.300 | 66.842 | 74.710 | 1.00 | 15.70 | B | C |
| ATOM | 1266 | CD1 | LEU | B | 267 | 7.953 | 67.016 | 76.155 | 1.00 | 12.23 | B | C |
| ATOM | 1267 | CD2 | LEU | B | 267 | 8.396 | 65.377 | 74.360 | 1.00 | 9.24 | B | C |
| ATOM | 1268 | C | LEU | B | 267 | 6.159 | 69.705 | 73.426 | 1.00 | 12.43 | B | C |
| ATOM | 1269 | O | LEU | B | 267 | 6.731 | 70.766 | 73.723 | 1.00 | 10.09 | B | O |
| ATOM | 1270 | N | SER | B | 268 | 5.459 | 69.547 | 72.305 | 1.00 | 11.56 | B | N |
| ATOM | 1271 | CA | SER | B | 268 | 5.303 | 70.617 | 71.316 | 1.00 | 9.65 | B | C |
| ATOM | 1272 | CB | SER | B | 268 | 4.637 | 70.049 | 70.060 | 1.00 | 7.32 | B | C |
| ATOM | 1273 | OG | SER | B | 268 | 4.249 | 71.073 | 69.169 | 1.00 | 12.01 | B | O |
| ATOM | 1274 | C | SER | B | 268 | 4.473 | 71.783 | 71.866 | 1.00 | 8.84 | B | C |
| ATOM | 1275 | O | SER | B | 268 | 4.910 | 72.926 | 71.829 | 1.00 | 11.31 | B | O |
| ATOM | 1276 | N | SER | B | 269 | 3.279 | 71.504 | 72.375 | 1.00 | 8.37 | B | N |
| ATOM | 1277 | CA | SER | B | 269 | 2.434 | 72.567 | 72.925 | 1.00 | 9.27 | B | C |
| ATOM | 1278 | CB | SER | B | 269 | 1.088 | 72.007 | 73.339 | 1.00 | 8.90 | B | C |
| ATOM | 1279 | OG | SER | B | 269 | 0.386 | 71.512 | 72.221 | 1.00 | 13.37 | B | O |
| ATOM | 1280 | C | SER | B | 269 | 3.073 | 73.250 | 74.126 | 1.00 | 9.46 | B | C |
| ATOM | 1281 | O | SER | B | 269 | 3.016 | 74.479 | 74.257 | 1.00 | 9.30 | B | O |
| ATOM | 1282 | N | LYS | B | 270 | 3.684 | 72.460 | 75.007 | 1.00 | 9.74 | B | N |
| ATOM | 1283 | CA | LYS | B | 270 | 4.330 | 73.038 | 76.189 | 1.00 | 12.13 | B | C |
| ATOM | 1284 | CB | LYS | B | 270 | 5.017 | 71.955 | 77.057 | 1.00 | 10.45 | B | C |
| ATOM | 1285 | CG | LYS | B | 270 | 5.269 | 72.432 | 78.507 | 1.00 | 12.17 | B | C |
| ATOM | 1286 | CD | LYS | B | 270 | 6.236 | 71.558 | 79.290 | 1.00 | 8.79 | B | C |
| ATOM | 1287 | CE | LYS | B | 270 | 6.661 | 72.262 | 80.588 | 1.00 | 14.36 | B | C |
| ATOM | 1288 | NZ | LYS | B | 270 | 7.814 | 71.583 | 81.302 | 1.00 | 12.58 | B | N |
| ATOM | 1289 | C | LYS | B | 270 | 5.353 | 74.092 | 75.780 | 1.00 | 10.92 | B | C |
| ATOM | 1290 | O | LYS | B | 270 | 5.420 | 75.168 | 76.383 | 1.00 | 11.75 | B | O |
| ATOM | 1291 | N | PHE | B | 271 | 6.143 | 73.800 | 74.746 | 1.00 | 11.54 | B | N |
| ATOM | 1292 | CA | PHE | B | 271 | 7.134 | 74.772 | 74.300 | 1.00 | 10.81 | B | C |
| ATOM | 1293 | CB | PHE | B | 271 | 8.045 | 74.199 | 73.215 | 1.00 | 11.56 | B | C |
| ATOM | 1294 | CG | PHE | B | 271 | 9.160 | 75.123 | 72.832 | 1.00 | 9.60 | B | C |
| ATOM | 1295 | CD1 | PHE | B | 271 | 10.296 | 75.230 | 73.631 | 1.00 | 11.09 | B | C |
| ATOM | 1296 | CD2 | PHE | B | 271 | 9.058 | 75.931 | 71.703 | 1.00 | 10.27 | B | C |
| ATOM | 1297 | CE1 | PHE | B | 271 | 11.317 | 76.134 | 73.317 | 1.00 | 9.95 | B | C |
| ATOM | 1298 | CE2 | PHE | B | 271 | 10.072 | 76.838 | 71.379 | 1.00 | 10.62 | B | C |
| ATOM | 1299 | CZ | PHE | B | 271 | 11.208 | 76.940 | 72.195 | 1.00 | 10.93 | B | C |
| ATOM | 1300 | C | PHE | B | 271 | 6.471 | 76.020 | 73.772 | 1.00 | 10.48 | B | C |
| ATOM | 1301 | O | PHE | B | 271 | 6.975 | 77.118 | 73.982 | 1.00 | 12.41 | B | O |
| ATOM | 1302 | N | GLN | B | 272 | 5.339 | 75.857 | 73.091 | 1.00 | 13.85 | B | N |
| ATOM | 1303 | CA | GLN | B | 272 | 4.628 | 77.012 | 72.544 | 1.00 | 16.09 | B | C |
| ATOM | 1304 | CB | GLN | B | 272 | 3.417 | 76.564 | 71.737 | 1.00 | 17.26 | B | C |
| ATOM | 1305 | CG | GLN | B | 272 | 3.585 | 76.801 | 70.252 | 1.00 | 28.51 | B | C |
| ATOM | 1306 | CD | GLN | B | 272 | 3.959 | 75.541 | 69.516 | 1.00 | 33.55 | B | C |
| ATOM | 1307 | OE1 | GLN | B | 272 | 3.089 | 74.827 | 69.008 | 1.00 | 36.96 | B | O |
| ATOM | 1308 | NE2 | GLN | B | 272 | 5.258 | 75.247 | 69.457 | 1.00 | 35.60 | B | N |
| ATOM | 1309 | C | GLN | B | 272 | 4.188 | 77.946 | 73.666 | 1.00 | 14.02 | B | C |
| ATOM | 1310 | O | GLN | B | 272 | 4.337 | 79.160 | 73.576 | 1.00 | 11.67 | B | O |
| ATOM | 1311 | N | VAL | B | 273 | 3.636 | 77.374 | 74.730 | 1.00 | 13.61 | B | N |
| ATOM | 1312 | CA | VAL | B | 273 | 3.227 | 78.197 | 75.859 | 1.00 | 10.93 | B | C |
| ATOM | 1313 | CB | VAL | B | 273 | 2.450 | 77.379 | 76.890 | 1.00 | 10.67 | B | C |
| ATOM | 1314 | CG1 | VAL | B | 273 | 2.106 | 78.248 | 78.087 | 1.00 | 11.99 | B | C |
| ATOM | 1315 | CG2 | VAL | B | 273 | 1.182 | 76.830 | 76.242 | 1.00 | 12.09 | B | C |
| ATOM | 1316 | C | VAL | B | 273 | 4.451 | 78.805 | 76.529 | 1.00 | 9.87 | B | C |
| ATOM | 1317 | O | VAL | B | 273 | 4.438 | 79.980 | 76.877 | 1.00 | 10.91 | B | O |
| ATOM | 1318 | N | HIS | B | 274 | 5.513 | 78.015 | 76.710 | 1.00 | 10.28 | B | N |
| ATOM | 1319 | CA | HIS | B | 274 | 6.726 | 78.547 | 77.328 | 1.00 | 11.54 | B | C |
| ATOM | 1320 | CB | HIS | B | 274 | 7.834 | 77.500 | 77.382 | 1.00 | 11.48 | B | C |
| ATOM | 1321 | CG | HIS | B | 274 | 9.175 | 78.067 | 77.754 | 1.00 | 12.27 | B | C |
| ATOM | 1322 | CD2 | HIS | B | 274 | 10.282 | 78.303 | 77.011 | 1.00 | 13.25 | B | C |
| ATOM | 1323 | ND1 | HIS | B | 274 | 9.497 | 78.440 | 79.042 | 1.00 | 14.08 | B | N |
| ATOM | 1324 | CE1 | HIS | B | 274 | 10.744 | 78.878 | 79.077 | 1.00 | 12.79 | B | C |
| ATOM | 1325 | NE2 | HIS | B | 274 | 11.243 | 78.805 | 77.856 | 1.00 | 11.95 | B | N |
| ATOM | 1326 | C | HIS | B | 274 | 7.267 | 79.750 | 76.570 | 1.00 | 13.23 | B | C |
| ATOM | 1327 | O | HIS | B | 274 | 7.598 | 80.784 | 77.171 | 1.00 | 15.08 | B | O |
| ATOM | 1328 | N | GLN | B | 275 | 7.369 | 79.620 | 75.253 | 1.00 | 13.07 | B | N |
| ATOM | 1329 | CA | GLN | B | 275 | 7.895 | 80.707 | 74.433 | 1.00 | 16.31 | B | C |
| ATOM | 1330 | CB | GLN | B | 275 | 8.083 | 80.249 | 72.978 | 1.00 | 21.18 | B | C |
| ATOM | 1331 | CG | GLN | B | 275 | 9.543 | 80.299 | 72.527 | 1.00 | 33.69 | B | C |
| ATOM | 1332 | CD | GLN | B | 275 | 9.717 | 80.445 | 71.003 | 1.00 | 40.11 | B | C |
| ATOM | 1333 | OE1 | GLN | B | 275 | 8.737 | 80.416 | 70.234 | 1.00 | 39.47 | B | O |
| ATOM | 1334 | NE2 | GLN | B | 275 | 10.978 | 80.607 | 70.563 | 1.00 | 36.77 | B | N |
| ATOM | 1335 | C | GLN | B | 275 | 7.065 | 81.975 | 74.446 | 1.00 | 11.88 | B | C |
| ATOM | 1336 | O | GLN | B | 275 | 7.597 | 83.069 | 74.563 | 1.00 | 13.15 | B | O |
| ATOM | 1337 | N | MET | B | 276 | 5.759 | 81.842 | 74.313 | 1.00 | 12.94 | B | N |
| ATOM | 1338 | CA | MET | B | 276 | 4.941 | 83.029 | 74.297 | 1.00 | 15.98 | B | C |
| ATOM | 1339 | CB | MET | B | 276 | 3.505 | 82.688 | 73.885 | 1.00 | 14.65 | B | C |
| ATOM | 1340 | CG | MET | B | 276 | 2.670 | 82.045 | 74.947 | 1.00 | 17.61 | B | C |
| ATOM | 1341 | SD | MET | B | 276 | 1.000 | 81.688 | 74.326 | 1.00 | 25.35 | B | S |
| ATOM | 1342 | CE | MET | B | 276 | 1.252 | 80.177 | 73.346 | 1.00 | 25.36 | B | C |
| ATOM | 1343 | C | MET | B | 276 | 4.970 | 83.732 | 75.649 | 1.00 | 17.51 | B | C |
| ATOM | 1344 | O | MET | B | 276 | 4.971 | 84.960 | 75.707 | 1.00 | 19.55 | B | O |
| ATOM | 1345 | N | LEU | B | 277 | 5.024 | 82.959 | 76.730 | 1.00 | 15.30 | B | N |
| ATOM | 1346 | CA | LEU | B | 277 | 5.045 | 83.522 | 78.069 | 1.00 | 15.00 | B | C |
| ATOM | 1347 | CB | LEU | B | 277 | 4.566 | 82.461 | 79.074 | 1.00 | 17.29 | B | C |
| ATOM | 1348 | CG | LEU | B | 277 | 3.155 | 82.491 | 79.672 | 1.00 | 18.72 | B | C |
| ATOM | 1349 | CD1 | LEU | B | 277 | 2.191 | 83.238 | 78.775 | 1.00 | 16.76 | B | C |
| ATOM | 1350 | CD2 | LEU | B | 277 | 2.692 | 81.069 | 79.889 | 1.00 | 17.53 | B | C |
| ATOM | 1351 | C | LEU | B | 277 | 6.416 | 84.045 | 78.518 | 1.00 | 15.32 | B | C |
| ATOM | 1352 | O | LEU | B | 277 | 6.492 | 85.082 | 79.179 | 1.00 | 12.35 | B | O |
| ATOM | 1353 | N | ASN | B | 278 | 7.491 | 83.349 | 78.129 | 1.00 | 14.93 | B | N |
| ATOM | 1354 | CA | ASN | B | 278 | 8.844 | 83.696 | 78.572 | 1.00 | 11.99 | B | C |
| ATOM | 1355 | CB | ASN | B | 278 | 9.410 | 82.523 | 79.382 | 1.00 | 13.11 | B | C |
| ATOM | 1356 | CG | ASN | B | 278 | 8.460 | 82.052 | 80.466 | 1.00 | 12.00 | B | C |
| ATOM | 1357 | OD1 | ASN | B | 278 | 8.016 | 80.902 | 80.466 | 1.00 | 13.34 | B | O |
| ATOM | 1358 | ND2 | ASN | B | 278 | 8.138 | 82.940 | 81.389 | 1.00 | 5.56 | B | N |
| ATOM | 1359 | C | ASN | B | 278 | 9.932 | 84.141 | 77.599 | 1.00 | 13.02 | B | C |
| ATOM | 1360 | O | ASN | B | 278 | 11.064 | 84.404 | 78.034 | 1.00 | 9.80 | B | O |
| ATOM | 1361 | N | GLU | B | 279 | 9.634 | 84.238 | 76.307 | 1.00 | 12.90 | B | N |
| ATOM | 1362 | CA | GLU | B | 279 | 10.673 | 84.630 | 75.348 | 1.00 | 15.99 | B | C |
| ATOM | 1363 | CB | GLU | B | 279 | 10.120 | 84.601 | 73.929 | 1.00 | 16.04 | B | C |
| ATOM | 1364 | CG | GLU | B | 279 | 8.995 | 85.579 | 73.705 | 1.00 | 20.09 | B | C |
| ATOM | 1365 | CD | GLU | B | 279 | 8.436 | 85.499 | 72.303 | 1.00 | 27.76 | B | C |
| ATOM | 1366 | OE1 | GLU | B | 279 | 9.215 | 85.180 | 71.372 | 1.00 | 30.42 | B | O |
| ATOM | 1367 | OE2 | GLU | B | 279 | 7.220 | 85.750 | 72.128 | 1.00 | 29.80 | B | O |
| ATOM | 1368 | C | GLU | B | 279 | 11.298 | 85.997 | 75.637 | 1.00 | 14.89 | B | C |
| ATOM | 1369 | O | GLU | B | 279 | 12.488 | 86.197 | 75.420 | 1.00 | 16.64 | B | O |
| ATOM | 1370 | N | MET | B | 280 | 10.512 | 86.945 | 76.127 | 1.00 | 16.50 | B | N |
| ATOM | 1371 | CA | MET | B | 280 | 11.070 | 88.261 | 76.442 | 1.00 | 16.73 | B | C |
| ATOM | 1372 | CB | MET | B | 280 | 9.944 | 89.249 | 76.758 | 1.00 | 22.06 | B | C |
| ATOM | 1373 | CG | MET | B | 280 | 9.242 | 89.810 | 75.511 | 1.00 | 32.17 | B | C |
| ATOM | 1374 | SD | MET | B | 280 | 10.337 | 89.999 | 74.019 | 1.00 | 45.85 | B | S |
| ATOM | 1375 | CE | MET | B | 280 | 11.072 | 91.659 | 74.353 | 1.00 | 35.95 | B | C |
| ATOM | 1376 | C | MET | B | 280 | 12.023 | 88.138 | 77.631 | 1.00 | 15.82 | B | C |
| ATOM | 1377 | O | MET | B | 280 | 12.992 | 88.883 | 77.750 | 1.00 | 14.45 | B | O |
| ATOM | 1378 | N | ASP | B | 281 | 11.757 | 87.165 | 78.492 | 1.00 | 14.04 | B | N |
| ATOM | 1379 | CA | ASP | B | 281 | 12.584 | 86.935 | 79.668 | 1.00 | 15.98 | B | C |
| ATOM | 1380 | CB | ASP | B | 281 | 11.804 | 86.089 | 80.671 | 1.00 | 16.45 | B | C |
| ATOM | 1381 | CG | ASP | B | 281 | 10.583 | 86.822 | 81.193 | 1.00 | 25.39 | B | C |
| ATOM | 1382 | OD1 | ASP | B | 281 | 9.456 | 86.585 | 80.674 | 1.00 | 24.64 | B | O |
| ATOM | 1383 | OD2 | ASP | B | 281 | 10.768 | 87.656 | 82.109 | 1.00 | 25.90 | B | O |
| ATOM | 1384 | C | ASP | B | 281 | 13.896 | 86.274 | 79.285 | 1.00 | 14.72 | B | C |
| ATOM | 1385 | O | ASP | B | 281 | 14.946 | 86.606 | 79.830 | 1.00 | 13.64 | B | O |
| ATOM | 1386 | N | GLU | B | 282 | 13.830 | 85.331 | 78.348 | 1.00 | 13.89 | B | N |
| ATOM | 1387 | CA | GLU | B | 282 | 15.031 | 84.668 | 77.866 | 1.00 | 11.41 | B | C |
| ATOM | 1388 | CB | GLU | B | 282 | 14.652 | 83.548 | 76.904 | 1.00 | 10.00 | B | C |
| ATOM | 1389 | CG | GLU | B | 282 | 14.039 | 82.349 | 77.596 | 1.00 | 9.60 | B | C |
| ATOM | 1390 | CD | GLU | B | 282 | 13.572 | 81.293 | 76.620 | 1.00 | 13.82 | B | C |
| ATOM | 1391 | OE1 | GLU | B | 282 | 13.219 | 81.670 | 75.482 | 1.00 | 14.51 | B | O |
| ATOM | 1392 | OE2 | GLU | B | 282 | 13.552 | 80.095 | 76.981 | 1.00 | 12.52 | B | O |
| ATOM | 1393 | C | GLU | B | 282 | 15.876 | 85.737 | 77.155 | 1.00 | 12.23 | B | C |
| ATOM | 1394 | O | GLU | B | 282 | 17.085 | 85.819 | 77.349 | 1.00 | 15.36 | B | O |
| ATOM | 1395 | N | LEU | B | 283 | 15.237 | 86.579 | 76.350 | 1.00 | 12.30 | B | N |
| ATOM | 1396 | CA | LEU | B | 283 | 15.961 | 87.643 | 75.650 | 1.00 | 13.04 | B | C |
| ATOM | 1397 | CB | LEU | B | 283 | 14.981 | 88.479 | 74.808 | 1.00 | 11.80 | B | C |
| ATOM | 1398 | CG | LEU | B | 283 | 15.405 | 89.142 | 73.485 | 1.00 | 16.57 | B | C |
| ATOM | 1399 | CD1 | LEU | B | 283 | 14.682 | 90.473 | 73.355 | 1.00 | 14.57 | B | C |
| ATOM | 1400 | CD2 | LEU | B | 283 | 16.916 | 89.319 | 73.389 | 1.00 | 12.44 | B | C |
| ATOM | 1401 | C | LEU | B | 283 | 16.685 | 88.566 | 76.641 | 1.00 | 13.94 | B | C |
| ATOM | 1402 | O | LEU | B | 283 | 17.815 | 89.014 | 76.398 | 1.00 | 14.23 | B | O |
| ATOM | 1403 | N | LYS | B | 284 | 16.020 | 88.871 | 77.751 | 1.00 | 16.15 | B | N |
| ATOM | 1404 | CA | LYS | B | 284 | 16.603 | 89.748 | 78.765 | 1.00 | 16.25 | B | C |
| ATOM | 1405 | CB | LYS | B | 284 | 15.637 | 89.908 | 79.940 | 1.00 | 19.75 | B | C |
| ATOM | 1406 | CG | LYS | B | 284 | 16.038 | 91.009 | 80.924 | 1.00 | 24.99 | B | C |
| ATOM | 1407 | CD | LYS | B | 284 | 15.239 | 90.894 | 82.218 | 1.00 | 28.89 | B | C |
| ATOM | 1408 | CE | LYS | B | 284 | 15.650 | 91.962 | 83.221 | 1.00 | 35.30 | B | C |
| ATOM | 1409 | NZ | LYS | B | 284 | 14.459 | 92.569 | 83.892 | 1.00 | 41.64 | B | N |
| ATOM | 1410 | C | LYS | B | 284 | 17.943 | 89.222 | 79.261 | 1.00 | 14.45 | B | C |
| ATOM | 1411 | O | LYS | B | 284 | 18.905 | 89.987 | 79.423 | 1.00 | 13.94 | B | O |
| ATOM | 1412 | N | GLU | B | 285 | 17.999 | 87.914 | 79.504 | 1.00 | 13.34 | B | N |
| ATOM | 1413 | CA | GLU | B | 285 | 19.227 | 87.289 | 79.964 | 1.00 | 12.06 | B | C |
| ATOM | 1414 | CB | GLU | B | 285 | 19.043 | 85.782 | 80.110 | 1.00 | 10.55 | B | C |
| ATOM | 1415 | CG | GLU | B | 285 | 18.254 | 85.331 | 81.311 | 1.00 | 14.97 | B | C |
| ATOM | 1416 | CD | GLU | B | 285 | 18.432 | 83.844 | 81.579 | 1.00 | 17.51 | B | C |
| ATOM | 1417 | OE1 | GLU | B | 285 | 19.574 | 83.425 | 81.904 | 1.00 | 15.62 | B | O |
| ATOM | 1418 | OE2 | GLU | B | 285 | 17.428 | 83.094 | 81.461 | 1.00 | 19.51 | B | O |
| ATOM | 1419 | C | GLU | B | 285 | 20.333 | 87.546 | 78.943 | 1.00 | 13.57 | B | C |
| ATOM | 1420 | O | GLU | B | 285 | 21.457 | 87.897 | 79.313 | 1.00 | 11.42 | B | O |
| ATOM | 1421 | N | LEU | B | 286 | 20.013 | 87.364 | 77.657 | 1.00 | 13.16 | B | N |
| ATOM | 1422 | CA | LEU | B | 286 | 21.007 | 87.554 | 76.589 | 1.00 | 16.32 | B | C |
| ATOM | 1423 | CB | LEU | B | 286 | 20.464 | 87.088 | 75.224 | 1.00 | 13.35 | B | C |
| ATOM | 1424 | CG | LEU | B | 286 | 19.895 | 85.675 | 74.943 | 1.00 | 16.74 | B | C |
| ATOM | 1425 | CD1 | LEU | B | 286 | 20.513 | 85.163 | 73.653 | 1.00 | 16.07 | B | C |
| ATOM | 1426 | CD2 | LEU | B | 286 | 20.127 | 84.692 | 76.064 | 1.00 | 10.87 | B | C |
| ATOM | 1427 | C | LEU | B | 286 | 21.450 | 89.012 | 76.485 | 1.00 | 15.69 | B | C |
| ATOM | 1428 | O | LEU | B | 286 | 22.647 | 89.302 | 76.374 | 1.00 | 16.09 | B | O |
| ATOM | 1429 | N | LYS | B | 287 | 20.492 | 89.934 | 76.520 | 1.00 | 17.03 | B | N |
| ATOM | 1430 | CA | LYS | B | 287 | 20.835 | 91.348 | 76.446 | 1.00 | 18.53 | B | C |
| ATOM | 1431 | CB | LYS | B | 287 | 19.586 | 92.213 | 76.471 | 1.00 | 16.64 | B | C |
| ATOM | 1432 | CG | LYS | B | 287 | 18.841 | 92.244 | 75.166 | 1.00 | 18.22 | B | C |
| ATOM | 1433 | CD | LYS | B | 287 | 17.381 | 92.562 | 75.415 | 1.00 | 19.40 | B | C |
| ATOM | 1434 | CE | LYS | B | 287 | 16.932 | 93.764 | 74.618 | 1.00 | 24.02 | B | C |
| ATOM | 1435 | NZ | LYS | B | 287 | 15.451 | 93.775 | 74.439 | 1.00 | 26.66 | B | N |
| ATOM | 1436 | C | LYS | B | 287 | 21.717 | 91.715 | 77.623 | 1.00 | 20.30 | B | C |
| ATOM | 1437 | O | LYS | B | 287 | 22.653 | 92.493 | 77.476 | 1.00 | 20.29 | B | O |
| ATOM | 1438 | N | ASN | B | 288 | 21.430 | 91.133 | 78.787 | 1.00 | 22.30 | B | N |
| ATOM | 1439 | CA | ASN | B | 288 | 22.208 | 91.416 | 79.993 | 1.00 | 22.55 | B | C |
| ATOM | 1440 | CB | ASN | B | 288 | 21.345 | 91.192 | 81.236 | 1.00 | 21.97 | B | C |
| ATOM | 1441 | CG | ASN | B | 288 | 20.293 | 92.276 | 81.404 | 1.00 | 25.95 | B | C |
| ATOM | 1442 | OD1 | ASN | B | 288 | 20.548 | 93.452 | 81.133 | 1.00 | 26.28 | B | O |
| ATOM | 1443 | ND2 | ASN | B | 288 | 19.110 | 91.889 | 81.847 | 1.00 | 28.18 | B | N |
| ATOM | 1444 | C | ASN | B | 288 | 23.502 | 90.619 | 80.106 | 1.00 | 23.71 | B | C |
| ATOM | 1445 | O | ASN | B | 288 | 24.208 | 90.729 | 81.101 | 1.00 | 23.78 | B | O |
| ATOM | 1446 | N | ASN | B | 289 | 23.800 | 89.819 | 79.085 | 1.00 | 21.88 | B | N |
| ATOM | 1447 | CA | ASN | B | 289 | 25.016 | 89.016 | 79.034 | 1.00 | 22.18 | B | C |
| ATOM | 1448 | CB | ASN | B | 289 | 24.703 | 87.639 | 78.447 | 1.00 | 14.18 | B | C |
| ATOM | 1449 | CG | ASN | B | 289 | 25.899 | 86.735 | 78.434 | 1.00 | 14.88 | B | C |
| ATOM | 1450 | OD1 | ASN | B | 289 | 26.677 | 86.723 | 79.369 | 1.00 | 15.70 | B | O |
| ATOM | 1451 | ND2 | ASN | B | 289 | 26.056 | 85.965 | 77.370 | 1.00 | 13.18 | B | N |
| ATOM | 1452 | C | ASN | B | 289 | 25.977 | 89.775 | 78.112 | 1.00 | 26.52 | B | C |
| ATOM | 1453 | O | ASN | B | 289 | 25.964 | 89.581 | 76.894 | 1.00 | 29.87 | B | O |
| ATOM | 1454 | N | PRO | B | 290 | 26.826 | 90.650 | 78.676 | 1.00 | 27.98 | B | N |
| ATOM | 1455 | CD | PRO | B | 290 | 26.976 | 90.946 | 80.112 | 1.00 | 27.28 | B | C |
| ATOM | 1456 | CA | PRO | B | 290 | 27.769 | 91.426 | 77.856 | 1.00 | 26.94 | B | C |
| ATOM | 1457 | CB | PRO | B | 290 | 28.273 | 92.488 | 78.821 | 1.00 | 29.73 | B | C |
| ATOM | 1458 | CG | PRO | B | 290 | 28.227 | 91.780 | 80.163 | 1.00 | 28.64 | B | C |
| ATOM | 1459 | C | PRO | B | 290 | 28.919 | 90.638 | 77.229 | 1.00 | 26.62 | B | C |
| ATOM | 1460 | O | PRO | B | 290 | 29.540 | 91.083 | 76.266 | 1.00 | 26.61 | B | O |
| ATOM | 1461 | N | HIS | B | 291 | 29.201 | 89.465 | 77.773 | 1.00 | 29.45 | B | N |
| ATOM | 1462 | CA | HIS | B | 291 | 30.296 | 88.645 | 77.273 | 1.00 | 34.40 | B | C |
| ATOM | 1463 | CB | HIS | B | 291 | 30.590 | 87.516 | 78.268 | 1.00 | 37.29 | B | C |
| ATOM | 1464 | CG | HIS | B | 291 | 30.936 | 88.011 | 79.634 | 1.00 | 45.03 | B | C |
| ATOM | 1465 | CD2 | HIS | B | 291 | 32.128 | 88.345 | 80.186 | 1.00 | 47.39 | B | C |
| ATOM | 1466 | ND1 | HIS | B | 291 | 29.977 | 88.307 | 80.579 | 1.00 | 46.16 | B | N |
| ATOM | 1467 | CE1 | HIS | B | 291 | 30.564 | 88.805 | 81.654 | 1.00 | 49.14 | B | C |
| ATOM | 1468 | NE2 | HIS | B | 291 | 31.868 | 88.839 | 81.442 | 1.00 | 49.16 | B | N |
| ATOM | 1469 | C | HIS | B | 291 | 30.051 | 88.038 | 75.904 | 1.00 | 35.25 | B | C |
| ATOM | 1470 | O | HIS | B | 291 | 30.983 | 87.558 | 75.263 | 1.00 | 37.59 | B | O |
| ATOM | 1471 | N | ARG | B | 292 | 28.814 | 88.081 | 75.427 | 1.00 | 31.87 | B | N |
| ATOM | 1472 | CA | ARG | B | 292 | 28.552 | 87.422 | 74.177 | 1.00 | 25.67 | B | C |
| ATOM | 1473 | CB | ARG | B | 292 | 28.582 | 85.906 | 74.434 | 1.00 | 25.63 | B | C |
| ATOM | 1474 | CG | ARG | B | 292 | 29.652 | 85.189 | 73.668 | 1.00 | 27.69 | B | C |
| ATOM | 1475 | CD | ARG | B | 292 | 30.094 | 83.969 | 74.368 | 1.00 | 26.60 | B | C |
| ATOM | 1476 | NE | ARG | B | 292 | 31.284 | 84.189 | 75.176 | 1.00 | 25.02 | B | N |
| ATOM | 1477 | CZ | ARG | B | 292 | 32.531 | 84.241 | 74.711 | 1.00 | 25.24 | B | C |
| ATOM | 1478 | NH1 | ARG | B | 292 | 32.802 | 84.101 | 73.415 | 1.00 | 25.50 | B | N |
| ATOM | 1479 | NH2 | ARG | B | 292 | 33.528 | 84.373 | 75.566 | 1.00 | 22.65 | B | N |
| ATOM | 1480 | C | ARG | B | 292 | 27.267 | 87.744 | 73.451 | 1.00 | 22.75 | B | C |
| ATOM | 1481 | O | ARG | B | 292 | 26.303 | 88.296 | 74.013 | 1.00 | 21.04 | B | O |
| ATOM | 1482 | N | ASP | B | 293 | 27.291 | 87.392 | 72.168 | 1.00 | 20.04 | B | N |
| ATOM | 1483 | CA | ASP | B | 293 | 26.126 | 87.469 | 71.302 | 1.00 | 19.09 | B | C |
| ATOM | 1484 | CB | ASP | B | 293 | 25.940 | 88.838 | 70.609 | 1.00 | 15.21 | B | C |
| ATOM | 1485 | CG | ASP | B | 293 | 27.075 | 89.232 | 69.716 | 1.00 | 17.42 | B | C |
| ATOM | 1486 | OD1 | ASP | B | 293 | 27.192 | 90.456 | 69.514 | 1.00 | 16.90 | B | O |
| ATOM | 1487 | OD2 | ASP | B | 293 | 27.829 | 88.372 | 69.210 | 1.00 | 16.64 | B | O |
| ATOM | 1488 | C | ASP | B | 293 | 26.301 | 86.309 | 70.334 | 1.00 | 17.82 | B | C |
| ATOM | 1489 | O | ASP | B | 293 | 27.266 | 85.560 | 70.450 | 1.00 | 17.10 | B | O |
| ATOM | 1490 | N | PHE | B | 294 | 25.365 | 86.111 | 69.420 | 1.00 | 19.40 | B | N |
| ATOM | 1491 | CA | PHE | B | 294 | 25.477 | 84.986 | 68.504 | 1.00 | 17.59 | B | C |
| ATOM | 1492 | CB | PHE | B | 294 | 24.365 | 85.028 | 67.463 | 1.00 | 15.57 | B | C |
| ATOM | 1493 | CG | PHE | B | 294 | 24.422 | 83.890 | 66.475 | 1.00 | 20.18 | B | C |
| ATOM | 1494 | CD1 | PHE | B | 294 | 23.976 | 82.615 | 66.837 | 1.00 | 18.59 | B | C |
| ATOM | 1495 | CD2 | PHE | B | 294 | 24.919 | 84.085 | 65.184 | 1.00 | 18.47 | B | C |
| ATOM | 1496 | CE1 | PHE | B | 294 | 24.020 | 81.539 | 65.934 | 1.00 | 18.43 | B | C |
| ATOM | 1497 | CE2 | PHE | B | 294 | 24.969 | 83.015 | 64.265 | 1.00 | 21.32 | B | C |
| ATOM | 1498 | CZ | PHE | B | 294 | 24.517 | 81.737 | 64.646 | 1.00 | 19.54 | B | C |
| ATOM | 1499 | C | PHE | B | 294 | 26.810 | 84.935 | 67.793 | 1.00 | 18.54 | B | C |
| ATOM | 1500 | O | PHE | B | 294 | 27.374 | 83.858 | 67.599 | 1.00 | 19.18 | B | O |
| ATOM | 1501 | N | TYR | B | 295 | 27.329 | 86.105 | 67.432 | 1.00 | 18.45 | B | N |
| ATOM | 1502 | CA | TYR | B | 295 | 28.571 | 86.170 | 66.680 | 1.00 | 18.69 | B | C |
| ATOM | 1503 | CB | TYR | B | 295 | 28.695 | 87.552 | 66.045 | 1.00 | 17.28 | B | C |
| ATOM | 1504 | CG | TYR | B | 295 | 27.535 | 87.790 | 65.109 | 1.00 | 18.41 | B | C |
| ATOM | 1505 | CD1 | TYR | B | 295 | 27.481 | 87.156 | 63.865 | 1.00 | 19.13 | B | C |
| ATOM | 1506 | CE1 | TYR | B | 295 | 26.368 | 87.296 | 63.032 | 1.00 | 18.09 | B | C |
| ATOM | 1507 | CD2 | TYR | B | 295 | 26.444 | 88.576 | 65.498 | 1.00 | 16.67 | B | C |
| ATOM | 1508 | CE2 | TYR | B | 295 | 25.326 | 88.724 | 64.671 | 1.00 | 19.02 | B | C |
| ATOM | 1509 | CZ | TYR | B | 295 | 25.300 | 88.079 | 63.439 | 1.00 | 21.92 | B | C |
| ATOM | 1510 | OH | TYR | B | 295 | 24.218 | 88.237 | 62.600 | 1.00 | 26.20 | B | O |
| ATOM | 1511 | C | TYR | B | 295 | 29.869 | 85.737 | 67.337 | 1.00 | 20.01 | B | C |
| ATOM | 1512 | O | TYR | B | 295 | 30.856 | 85.524 | 66.643 | 1.00 | 22.94 | B | O |
| ATOM | 1513 | N | ASN | B | 296 | 29.916 | 85.602 | 68.654 | 1.00 | 17.22 | B | N |
| ATOM | 1514 | CA | ASN | B | 296 | 31.159 | 85.099 | 69.214 | 1.00 | 14.38 | B | C |
| ATOM | 1515 | CB | ASN | B | 296 | 31.950 | 86.168 | 69.981 | 1.00 | 14.89 | B | C |
| ATOM | 1516 | CG | ASN | B | 296 | 31.165 | 86.829 | 71.076 | 1.00 | 14.57 | B | C |
| ATOM | 1517 | OD1 | ASN | B | 296 | 31.733 | 87.582 | 71.857 | 1.00 | 20.46 | B | O |
| ATOM | 1518 | ND2 | ASN | B | 296 | 29.869 | 86.571 | 71.143 | 1.00 | 14.45 | B | N |
| ATOM | 1519 | C | ASN | B | 296 | 30.948 | 83.851 | 70.052 | 1.00 | 15.41 | B | C |
| ATOM | 1520 | O | ASN | B | 296 | 31.691 | 83.581 | 70.998 | 1.00 | 16.11 | B | O |
| ATOM | 1521 | N | CYS | B | 297 | 29.917 | 83.097 | 69.669 | 1.00 | 14.78 | B | N |
| ATOM | 1522 | CA | CYS | B | 297 | 29.576 | 81.802 | 70.258 | 1.00 | 16.64 | B | C |
| ATOM | 1523 | CB | CYS | B | 297 | 28.060 | 81.565 | 70.249 | 1.00 | 18.56 | B | C |
| ATOM | 1524 | SG | CYS | B | 297 | 27.156 | 82.468 | 71.503 | 1.00 | 29.65 | B | S |
| ATOM | 1525 | C | CYS | B | 297 | 30.183 | 80.841 | 69.242 | 1.00 | 15.45 | B | C |
| ATOM | 1526 | O | CYS | B | 297 | 30.214 | 81.158 | 68.055 | 1.00 | 16.54 | B | O |
| ATOM | 1527 | N | ARG | B | 298 | 30.662 | 79.684 | 69.676 | 1.00 | 14.55 | B | N |
| ATOM | 1528 | CA | ARG | B | 298 | 31.209 | 78.740 | 68.716 | 1.00 | 14.11 | B | C |
| ATOM | 1529 | CB | ARG | B | 298 | 32.192 | 77.798 | 69.399 | 1.00 | 13.57 | B | C |
| ATOM | 1530 | CG | ARG | B | 298 | 33.609 | 78.300 | 69.390 | 1.00 | 12.00 | B | C |
| ATOM | 1531 | CD | ARG | B | 298 | 33.776 | 79.427 | 70.376 | 1.00 | 13.19 | B | C |
| ATOM | 1532 | NE | ARG | B | 298 | 35.159 | 79.885 | 70.414 | 1.00 | 15.32 | B | N |
| ATOM | 1533 | CZ | ARG | B | 298 | 35.633 | 80.792 | 71.272 | 1.00 | 19.69 | B | C |
| ATOM | 1534 | NH1 | ARG | B | 298 | 34.835 | 81.347 | 72.179 | 1.00 | 16.88 | B | N |
| ATOM | 1535 | NH2 | ARG | B | 298 | 36.908 | 81.165 | 71.210 | 1.00 | 19.63 | B | N |
| ATOM | 1536 | C | ARG | B | 298 | 30.062 | 77.939 | 68.099 | 1.00 | 16.10 | B | C |
| ATOM | 1537 | O | ARG | B | 298 | 29.067 | 77.638 | 68.772 | 1.00 | 15.10 | B | O |
| ATOM | 1538 | N | LYS | B | 299 | 30.202 | 77.619 | 66.812 | 1.00 | 17.64 | B | N |
| ATOM | 1539 | CA | LYS | B | 299 | 29.210 | 76.832 | 66.054 | 1.00 | 15.16 | B | C |
| ATOM | 1540 | CB | LYS | B | 299 | 28.519 | 77.685 | 64.999 | 1.00 | 13.54 | B | C |
| ATOM | 1541 | CG | LYS | B | 299 | 27.339 | 78.459 | 65.495 | 1.00 | 17.14 | B | C |
| ATOM | 1542 | CD | LYS | B | 299 | 27.790 | 79.720 | 66.168 | 1.00 | 17.57 | B | C |
| ATOM | 1543 | CE | LYS | B | 299 | 27.959 | 80.852 | 65.182 | 1.00 | 16.81 | B | C |
| ATOM | 1544 | NZ | LYS | B | 299 | 28.729 | 81.968 | 65.798 | 1.00 | 11.59 | B | N |
| ATOM | 1545 | C | LYS | B | 299 | 30.014 | 75.771 | 65.339 | 1.00 | 13.06 | B | C |
| ATOM | 1546 | O | LYS | B | 299 | 31.060 | 76.073 | 64.787 | 1.00 | 12.48 | B | O |
| ATOM | 1547 | N | VAL | B | 300 | 29.542 | 74.536 | 65.341 | 1.00 | 10.09 | B | N |
| ATOM | 1548 | CA | VAL | B | 300 | 30.285 | 73.481 | 64.684 | 1.00 | 9.46 | B | C |
| ATOM | 1549 | CB | VAL | B | 300 | 30.695 | 72.401 | 65.689 | 1.00 | 9.39 | B | C |
| ATOM | 1550 | CG1 | VAL | B | 300 | 31.561 | 71.332 | 65.003 | 1.00 | 9.20 | B | C |
| ATOM | 1551 | CG2 | VAL | B | 300 | 31.436 | 73.049 | 66.851 | 1.00 | 7.18 | B | C |
| ATOM | 1552 | C | VAL | B | 300 | 29.451 | 72.849 | 63.578 | 1.00 | 13.62 | B | C |
| ATOM | 1553 | O | VAL | B | 300 | 28.249 | 72.600 | 63.767 | 1.00 | 12.02 | B | O |
| ATOM | 1554 | N | ASP | B | 301 | 30.080 | 72.627 | 62.415 | 1.00 | 13.02 | B | N |
| ATOM | 1555 | CA | ASP | B | 301 | 29.405 | 71.985 | 61.278 | 1.00 | 12.19 | B | C |
| ATOM | 1556 | CB | ASP | B | 301 | 30.061 | 72.386 | 59.955 | 1.00 | 12.54 | B | C |
| ATOM | 1557 | CG | ASP | B | 301 | 29.171 | 72.120 | 58.753 | 1.00 | 12.73 | B | C |
| ATOM | 1558 | OD1 | ASP | B | 301 | 29.415 | 72.766 | 57.711 | 1.00 | 15.82 | B | O |
| ATOM | 1559 | OD2 | ASP | B | 301 | 28.247 | 71.273 | 58.830 | 1.00 | 10.85 | B | O |
| ATOM | 1560 | C | ASP | B | 301 | 29.607 | 70.506 | 61.550 | 1.00 | 10.50 | B | C |
| ATOM | 1561 | O | ASP | B | 301 | 30.640 | 69.928 | 61.213 | 1.00 | 7.96 | B | O |
| ATOM | 1562 | N | THR | B | 302 | 28.597 | 69.914 | 62.176 | 1.00 | 10.19 | B | N |
| ATOM | 1563 | CA | THR | B | 302 | 28.627 | 68.529 | 62.607 | 1.00 | 11.69 | B | C |
| ATOM | 1564 | CB | THR | B | 302 | 27.601 | 68.358 | 63.719 | 1.00 | 9.65 | B | C |
| ATOM | 1565 | OG1 | THR | B | 302 | 26.378 | 68.980 | 63.303 | 1.00 | 14.01 | B | O |
| ATOM | 1566 | CG2 | THR | B | 302 | 28.078 | 69.052 | 64.992 | 1.00 | 6.67 | B | C |
| ATOM | 1567 | C | THR | B | 302 | 28.401 | 67.459 | 61.530 | 1.00 | 15.35 | B | C |
| ATOM | 1568 | O | THR | B | 302 | 28.507 | 66.253 | 61.804 | 1.00 | 14.47 | B | O |
| ATOM | 1569 | N | HIS | B | 303 | 28.072 | 67.890 | 60.320 | 1.00 | 13.71 | B | N |
| ATOM | 1570 | CA | HIS | B | 303 | 27.841 | 66.959 | 59.223 | 1.00 | 13.71 | B | C |
| ATOM | 1571 | CB | HIS | B | 303 | 26.367 | 66.545 | 59.185 | 1.00 | 14.45 | B | C |
| ATOM | 1572 | CG | HIS | B | 303 | 25.927 | 66.015 | 57.852 | 1.00 | 19.48 | B | C |
| ATOM | 1573 | CD2 | HIS | B | 303 | 26.504 | 65.118 | 57.015 | 1.00 | 16.09 | B | C |
| ATOM | 1574 | ND1 | HIS | B | 303 | 24.747 | 66.403 | 57.247 | 1.00 | 17.77 | B | N |
| ATOM | 1575 | CE1 | HIS | B | 303 | 24.618 | 65.765 | 56.099 | 1.00 | 14.41 | B | C |
| ATOM | 1576 | NE2 | HIS | B | 303 | 25.669 | 64.981 | 55.934 | 1.00 | 20.34 | B | N |
| ATOM | 1577 | C | HIS | B | 303 | 28.244 | 67.651 | 57.921 | 1.00 | 13.37 | B | C |
| ATOM | 1578 | O | HIS | B | 303 | 27.484 | 68.450 | 57.365 | 1.00 | 11.94 | B | O |
| ATOM | 1579 | N | ILE | B | 304 | 29.462 | 67.357 | 57.467 | 1.00 | 13.51 | B | N |
| ATOM | 1580 | CA | ILE | B | 304 | 30.007 | 67.941 | 56.249 | 1.00 | 13.95 | B | C |
| ATOM | 1581 | CB | ILE | B | 304 | 30.689 | 69.309 | 56.537 | 1.00 | 11.85 | B | C |
| ATOM | 1582 | CG2 | ILE | B | 304 | 31.673 | 69.170 | 57.673 | 1.00 | 9.16 | B | C |
| ATOM | 1583 | CG1 | ILE | B | 304 | 31.370 | 69.829 | 55.272 | 1.00 | 10.83 | B | C |
| ATOM | 1584 | CD1 | ILE | B | 304 | 31.796 | 71.261 | 55.343 | 1.00 | 13.66 | B | C |
| ATOM | 1585 | C | ILE | B | 304 | 31.026 | 66.983 | 55.629 | 1.00 | 15.96 | B | C |
| ATOM | 1586 | O | ILE | B | 304 | 31.845 | 66.403 | 56.340 | 1.00 | 15.49 | B | O |
| ATOM | 1587 | N | HIS | B | 305 | 30.951 | 66.816 | 54.301 | 1.00 | 17.25 | B | N |
| ATOM | 1588 | CA | HIS | B | 305 | 31.844 | 65.925 | 53.541 | 1.00 | 12.57 | B | C |
| ATOM | 1589 | CB | HIS | B | 305 | 31.049 | 65.236 | 52.421 | 1.00 | 12.56 | B | C |
| ATOM | 1590 | CG | HIS | B | 305 | 29.808 | 64.540 | 52.901 | 1.00 | 11.01 | B | C |
| ATOM | 1591 | CD2 | HIS | B | 305 | 28.547 | 64.997 | 53.106 | 1.00 | 14.58 | B | C |
| ATOM | 1592 | ND1 | HIS | B | 305 | 29.791 | 63.212 | 53.270 | 1.00 | 12.20 | B | N |
| ATOM | 1593 | CE1 | HIS | B | 305 | 28.580 | 62.879 | 53.683 | 1.00 | 9.11 | B | C |
| ATOM | 1594 | NE2 | HIS | B | 305 | 27.804 | 63.946 | 53.594 | 1.00 | 9.14 | B | N |
| ATOM | 1595 | C | HIS | B | 305 | 33.013 | 66.732 | 52.963 | 1.00 | 11.92 | B | C |
| ATOM | 1596 | O | HIS | B | 305 | 32.818 | 67.765 | 52.334 | 1.00 | 14.76 | B | O |
| ATOM | 1597 | N | ALA | B | 306 | 34.230 | 66.259 | 53.195 | 1.00 | 13.16 | B | N |
| ATOM | 1598 | CA | ALA | B | 306 | 35.447 | 66.934 | 52.743 | 1.00 | 13.59 | B | C |
| ATOM | 1599 | CB | ALA | B | 306 | 36.679 | 66.106 | 53.151 | 1.00 | 13.69 | B | C |
| ATOM | 1600 | C | ALA | B | 306 | 35.496 | 67.222 | 51.247 | 1.00 | 13.79 | B | C |
| ATOM | 1601 | O | ALA | B | 306 | 35.940 | 68.287 | 50.823 | 1.00 | 13.34 | B | O |
| ATOM | 1602 | N | ALA | B | 307 | 35.047 | 66.266 | 50.448 | 1.00 | 15.92 | B | N |
| ATOM | 1603 | CA | ALA | B | 307 | 35.058 | 66.421 | 48.994 | 1.00 | 16.18 | B | C |
| ATOM | 1604 | CB | ALA | B | 307 | 34.642 | 65.125 | 48.339 | 1.00 | 11.38 | B | C |
| ATOM | 1605 | C | ALA | B | 307 | 34.151 | 67.560 | 48.526 | 1.00 | 18.54 | B | C |
| ATOM | 1606 | O | ALA | B | 307 | 34.166 | 67.911 | 47.347 | 1.00 | 21.77 | B | O |
| ATOM | 1607 | N | ALA | B | 308 | 33.373 | 68.147 | 49.442 | 1.00 | 19.81 | B | N |
| ATOM | 1608 | CA | ALA | B | 308 | 32.473 | 69.242 | 49.080 | 1.00 | 17.29 | B | C |
| ATOM | 1609 | CB | ALA | B | 308 | 31.059 | 68.724 | 48.942 | 1.00 | 19.33 | B | C |
| ATOM | 1610 | C | ALA | B | 308 | 32.487 | 70.383 | 50.076 | 1.00 | 17.64 | B | C |
| ATOM | 1611 | O | ALA | B | 308 | 31.580 | 71.220 | 50.076 | 1.00 | 18.39 | B | O |
| ATOM | 1612 | N | CYS | B | 309 | 33.514 | 70.444 | 50.912 | 1.00 | 16.75 | B | N |
| ATOM | 1613 | CA | CYS | B | 309 | 33.570 | 71.493 | 51.925 | 1.00 | 18.53 | B | C |
| ATOM | 1614 | CB | CYS | B | 309 | 34.591 | 71.133 | 53.006 | 1.00 | 18.68 | B | C |
| ATOM | 1615 | SG | CYS | B | 309 | 36.304 | 71.024 | 52.425 | 1.00 | 21.40 | B | S |
| ATOM | 1616 | C | CYS | B | 309 | 33.870 | 72.886 | 51.395 | 1.00 | 19.97 | B | C |
| ATOM | 1617 | O | CYS | B | 309 | 33.743 | 73.871 | 52.126 | 1.00 | 19.88 | B | O |
| ATOM | 1618 | N | MET | B | 310 | 34.270 | 72.977 | 50.129 | 1.00 | 21.42 | B | N |
| ATOM | 1619 | CA | MET | B | 310 | 34.586 | 74.275 | 49.524 | 1.00 | 20.77 | B | C |
| ATOM | 1620 | CB | MET | B | 310 | 35.887 | 74.161 | 48.709 | 1.00 | 19.65 | B | C |
| ATOM | 1621 | CG | MET | B | 310 | 35.733 | 73.494 | 47.335 | 1.00 | 15.56 | B | C |
| ATOM | 1622 | SD | MET | B | 310 | 35.200 | 71.779 | 47.412 | 1.00 | 16.98 | B | S |
| ATOM | 1623 | CE | MET | B | 310 | 36.558 | 70.990 | 48.304 | 1.00 | 13.12 | B | C |
| ATOM | 1624 | C | MET | B | 310 | 33.451 | 74.831 | 48.641 | 1.00 | 20.46 | B | C |
| ATOM | 1625 | O | MET | B | 310 | 32.669 | 74.072 | 48.050 | 1.00 | 19.84 | B | O |
| ATOM | 1626 | N | ASN | B | 311 | 33.369 | 76.157 | 48.567 | 1.00 | 19.38 | B | N |
| ATOM | 1627 | CA | ASN | B | 311 | 32.359 | 76.829 | 47.755 | 1.00 | 19.74 | B | C |
| ATOM | 1628 | CB | ASN | B | 311 | 32.339 | 78.333 | 48.085 | 1.00 | 23.11 | B | C |
| ATOM | 1629 | CG | ASN | B | 311 | 31.252 | 79.094 | 47.328 | 1.00 | 28.09 | B | C |
| ATOM | 1630 | OD1 | ASN | B | 311 | 30.061 | 78.806 | 47.462 | 1.00 | 30.06 | B | O |
| ATOM | 1631 | ND2 | ASN | B | 311 | 31.662 | 80.072 | 46.533 | 1.00 | 30.65 | B | N |
| ATOM | 1632 | C | ASN | B | 311 | 32.717 | 76.631 | 46.283 | 1.00 | 20.24 | B | C |
| ATOM | 1633 | O | ASN | B | 311 | 33.885 | 76.458 | 45.940 | 1.00 | 17.77 | B | O |
| ATOM | 1634 | N | GLN | B | 312 | 31.712 | 76.651 | 45.414 | 1.00 | 20.56 | B | N |
| ATOM | 1635 | CA | GLN | B | 312 | 31.957 | 76.499 | 43.992 | 1.00 | 20.64 | B | C |
| ATOM | 1636 | CB | GLN | B | 312 | 30.633 | 76.521 | 43.238 | 1.00 | 20.36 | B | C |
| ATOM | 1637 | CG | GLN | B | 312 | 29.864 | 77.824 | 43.396 | 1.00 | 20.64 | B | C |
| ATOM | 1638 | CD | GLN | B | 312 | 28.538 | 77.767 | 42.680 | 1.00 | 20.37 | B | C |
| ATOM | 1639 | OE1 | GLN | B | 312 | 28.331 | 76.883 | 41.849 | 1.00 | 21.83 | B | O |
| ATOM | 1640 | NE2 | GLN | B | 312 | 27.626 | 78.694 | 42.999 | 1.00 | 15.63 | B | N |
| ATOM | 1641 | C | GLN | B | 312 | 32.890 | 77.613 | 43.466 | 1.00 | 20.79 | B | C |
| ATOM | 1642 | O | GLN | B | 312 | 33.733 | 77.363 | 42.601 | 1.00 | 22.07 | B | O |
| ATOM | 1643 | N | LYS | B | 313 | 32.758 | 78.829 | 43.995 | 1.00 | 19.47 | B | N |
| ATOM | 1644 | CA | LYS | B | 313 | 33.602 | 79.948 | 43.555 | 1.00 | 19.04 | B | C |
| ATOM | 1645 | CB | LYS | B | 313 | 33.091 | 81.273 | 44.121 | 1.00 | 22.36 | B | C |
| ATOM | 1646 | CG | LYS | B | 313 | 31.760 | 81.730 | 43.552 | 1.00 | 25.73 | B | C |
| ATOM | 1647 | CD | LYS | B | 313 | 31.566 | 83.222 | 43.782 | 1.00 | 27.81 | B | C |
| ATOM | 1648 | CE | LYS | B | 313 | 31.121 | 83.501 | 45.187 | 1.00 | 30.15 | B | C |
| ATOM | 1649 | NZ | LYS | B | 313 | 31.051 | 84.962 | 45.414 | 1.00 | 33.67 | B | N |
| ATOM | 1650 | C | LYS | B | 313 | 35.039 | 79.758 | 43.996 | 1.00 | 18.59 | B | C |
| ATOM | 1651 | O | LYS | B | 313 | 35.970 | 80.280 | 43.384 | 1.00 | 19.80 | B | O |
| ATOM | 1652 | N | HIS | B | 314 | 35.206 | 79.017 | 45.080 | 1.00 | 17.80 | B | N |
| ATOM | 1653 | CA | HIS | B | 314 | 36.512 | 78.716 | 45.647 | 1.00 | 16.08 | B | C |
| ATOM | 1654 | CB | HIS | B | 314 | 36.303 | 78.188 | 47.076 | 1.00 | 20.91 | B | C |
| ATOM | 1655 | CG | HIS | B | 314 | 37.565 | 77.857 | 47.806 | 1.00 | 21.45 | B | C |
| ATOM | 1656 | CD2 | HIS | B | 314 | 37.764 | 77.277 | 49.012 | 1.00 | 19.27 | B | C |
| ATOM | 1657 | ND1 | HIS | B | 314 | 38.818 | 78.109 | 47.289 | 1.00 | 25.06 | B | N |
| ATOM | 1658 | CE1 | HIS | B | 314 | 39.736 | 77.695 | 48.144 | 1.00 | 24.04 | B | C |
| ATOM | 1659 | NE2 | HIS | B | 314 | 39.122 | 77.187 | 49.199 | 1.00 | 25.80 | B | N |
| ATOM | 1660 | C | HIS | B | 314 | 37.156 | 77.652 | 44.747 | 1.00 | 15.10 | B | C |
| ATOM | 1661 | O | HIS | B | 314 | 38.322 | 77.751 | 44.381 | 1.00 | 13.72 | B | O |
| ATOM | 1662 | N | LEU | B | 315 | 36.395 | 76.629 | 44.391 | 1.00 | 13.64 | B | N |
| ATOM | 1663 | CA | LEU | B | 315 | 36.920 | 75.593 | 43.511 | 1.00 | 17.29 | B | C |
| ATOM | 1664 | CB | LEU | B | 315 | 35.870 | 74.499 | 43.295 | 1.00 | 15.36 | B | C |
| ATOM | 1665 | CG | LEU | B | 315 | 36.242 | 73.457 | 42.236 | 1.00 | 14.69 | B | C |
| ATOM | 1666 | CD1 | LEU | B | 315 | 37.561 | 72.792 | 42.625 | 1.00 | 12.58 | B | C |
| ATOM | 1667 | CD2 | LEU | B | 315 | 35.114 | 72.427 | 42.089 | 1.00 | 14.24 | B | C |
| ATOM | 1668 | C | LEU | B | 315 | 37.304 | 76.217 | 42.156 | 1.00 | 18.21 | B | C |
| ATOM | 1669 | O | LEU | B | 315 | 38.372 | 75.924 | 41.605 | 1.00 | 18.82 | B | O |
| ATOM | 1670 | N | LEU | B | 316 | 36.435 | 77.084 | 41.631 | 1.00 | 18.31 | B | N |
| ATOM | 1671 | CA | LEU | B | 316 | 36.678 | 77.752 | 40.350 | 1.00 | 17.78 | B | C |
| ATOM | 1672 | CB | LEU | B | 316 | 35.517 | 78.698 | 40.024 | 1.00 | 14.70 | B | C |
| ATOM | 1673 | CG | LEU | B | 316 | 35.585 | 79.412 | 38.661 | 1.00 | 17.25 | B | C |
| ATOM | 1674 | CD1 | LEU | B | 316 | 35.539 | 78.400 | 37.528 | 1.00 | 15.21 | B | C |
| ATOM | 1675 | CD2 | LEU | B | 316 | 34.425 | 80.378 | 38.523 | 1.00 | 14.51 | B | C |
| ATOM | 1676 | C | LEU | B | 316 | 37.993 | 78.525 | 40.391 | 1.00 | 17.82 | B | C |
| ATOM | 1677 | O | LEU | B | 316 | 38.860 | 78.371 | 39.541 | 1.00 | 20.17 | B | O |
| ATOM | 1678 | N | ARG | B | 317 | 38.146 | 79.354 | 41.403 | 1.00 | 20.92 | B | N |
| ATOM | 1679 | CA | ARG | B | 317 | 39.355 | 80.142 | 41.576 | 1.00 | 19.34 | B | C |
| ATOM | 1680 | CB | ARG | B | 317 | 39.208 | 80.976 | 42.849 | 1.00 | 20.54 | B | C |
| ATOM | 1681 | CG | ARG | B | 317 | 40.414 | 81.790 | 43.238 | 1.00 | 29.79 | B | C |
| ATOM | 1682 | CD | ARG | B | 317 | 40.047 | 82.853 | 44.293 | 1.00 | 36.33 | B | C |
| ATOM | 1683 | NE | ARG | B | 317 | 39.242 | 82.326 | 45.406 | 1.00 | 40.47 | B | N |
| ATOM | 1684 | CZ | ARG | B | 317 | 37.940 | 82.568 | 45.574 | 1.00 | 42.06 | B | C |
| ATOM | 1685 | NH1 | ARG | B | 317 | 37.282 | 83.333 | 44.697 | 1.00 | 43.82 | B | N |
| ATOM | 1686 | NH2 | ARG | B | 317 | 37.293 | 82.051 | 46.615 | 1.00 | 36.83 | B | N |
| ATOM | 1687 | C | ARG | B | 317 | 40.616 | 79.264 | 41.651 | 1.00 | 19.94 | B | C |
| ATOM | 1688 | O | ARG | B | 317 | 41.667 | 79.619 | 41.101 | 1.00 | 18.56 | B | O |
| ATOM | 1689 | N | PHE | B | 318 | 40.524 | 78.123 | 42.333 | 1.00 | 17.97 | B | N |
| ATOM | 1690 | CA | PHE | B | 318 | 41.681 | 77.237 | 42.462 | 1.00 | 18.61 | B | C |
| ATOM | 1691 | CB | PHE | B | 318 | 41.438 | 76.140 | 43.511 | 1.00 | 16.14 | B | C |
| ATOM | 1692 | CG | PHE | B | 318 | 42.632 | 75.240 | 43.716 | 1.00 | 16.80 | B | C |
| ATOM | 1693 | CD1 | PHE | B | 318 | 43.630 | 75.574 | 44.636 | 1.00 | 18.11 | B | C |
| ATOM | 1694 | CD2 | PHE | B | 318 | 42.792 | 74.084 | 42.957 | 1.00 | 14.62 | B | C |
| ATOM | 1695 | CE1 | PHE | B | 318 | 44.774 | 74.768 | 44.794 | 1.00 | 17.60 | B | C |
| ATOM | 1696 | CE2 | PHE | B | 318 | 43.927 | 73.276 | 43.108 | 1.00 | 16.33 | B | C |
| ATOM | 1697 | CZ | PHE | B | 318 | 44.920 | 73.619 | 44.027 | 1.00 | 13.79 | B | C |
| ATOM | 1698 | C | PHE | B | 318 | 42.058 | 76.561 | 41.147 | 1.00 | 17.21 | B | C |
| ATOM | 1699 | O | PHE | B | 318 | 43.239 | 76.396 | 40.845 | 1.00 | 18.68 | B | O |
| ATOM | 1700 | N | ILE | B | 319 | 41.058 | 76.143 | 40.381 | 1.00 | 17.45 | B | N |
| ATOM | 1701 | CA | ILE | B | 319 | 41.332 | 75.488 | 39.115 | 1.00 | 15.56 | B | C |
| ATOM | 1702 | CB | ILE | B | 319 | 40.031 | 75.116 | 38.412 | 1.00 | 13.64 | B | C |
| ATOM | 1703 | CG2 | ILE | B | 319 | 40.309 | 74.675 | 36.999 | 1.00 | 14.74 | B | C |
| ATOM | 1704 | CG1 | ILE | B | 319 | 39.350 | 73.984 | 39.174 | 1.00 | 11.69 | B | C |
| ATOM | 1705 | CD1 | ILE | B | 319 | 37.957 | 73.692 | 38.709 | 1.00 | 13.37 | B | C |
| ATOM | 1706 | C | ILE | B | 319 | 42.157 | 76.437 | 38.250 | 1.00 | 17.93 | B | C |
| ATOM | 1707 | O | ILE | B | 319 | 43.209 | 76.060 | 37.738 | 1.00 | 16.81 | B | O |
| ATOM | 1708 | N | LYS | B | 320 | 41.691 | 77.680 | 38.132 | 1.00 | 18.44 | B | N |
| ATOM | 1709 | CA | LYS | B | 320 | 42.368 | 78.701 | 37.337 | 1.00 | 21.19 | B | C |
| ATOM | 1710 | CB | LYS | B | 320 | 41.544 | 79.983 | 37.322 | 1.00 | 20.37 | B | C |
| ATOM | 1711 | CG | LYS | B | 320 | 40.256 | 79.849 | 36.539 | 1.00 | 21.96 | B | C |
| ATOM | 1712 | CD | LYS | B | 320 | 39.471 | 81.142 | 36.537 | 1.00 | 17.39 | B | C |
| ATOM | 1713 | CE | LYS | B | 320 | 38.137 | 80.937 | 35.867 | 1.00 | 14.75 | B | C |
| ATOM | 1714 | NZ | LYS | B | 320 | 37.612 | 82.228 | 35.406 | 1.00 | 20.21 | B | N |
| ATOM | 1715 | C | LYS | B | 320 | 43.774 | 79.020 | 37.821 | 1.00 | 22.66 | B | C |
| ATOM | 1716 | O | LYS | B | 320 | 44.677 | 79.251 | 37.022 | 1.00 | 23.73 | B | O |
| ATOM | 1717 | N | LYS | B | 321 | 43.957 | 79.046 | 39.131 | 1.00 | 23.89 | B | N |
| ATOM | 1718 | CA | LYS | B | 321 | 45.267 | 79.314 | 39.693 | 1.00 | 23.44 | B | C |
| ATOM | 1719 | CB | LYS | B | 321 | 45.155 | 79.586 | 41.189 | 1.00 | 25.60 | B | C |
| ATOM | 1720 | CG | LYS | B | 321 | 46.436 | 80.086 | 41.815 | 1.00 | 29.62 | B | C |
| ATOM | 1721 | CD | LYS | B | 321 | 46.888 | 81.384 | 41.167 | 1.00 | 36.39 | B | C |
| ATOM | 1722 | CE | LYS | B | 321 | 48.035 | 82.030 | 41.938 | 1.00 | 37.44 | B | C |
| ATOM | 1723 | NZ | LYS | B | 321 | 49.249 | 81.167 | 41.932 | 1.00 | 41.92 | B | N |
| ATOM | 1724 | C | LYS | B | 321 | 46.191 | 78.132 | 39.459 | 1.00 | 23.33 | B | C |
| ATOM | 1725 | O | LYS | B | 321 | 47.377 | 78.321 | 39.237 | 1.00 | 25.00 | B | O |
| ATOM | 1726 | N | SER | B | 322 | 45.653 | 76.915 | 39.504 | 1.00 | 23.12 | B | N |
| ATOM | 1727 | CA | SER | B | 322 | 46.485 | 75.733 | 39.285 | 1.00 | 23.06 | B | C |
| ATOM | 1728 | CB | SER | B | 322 | 45.687 | 74.451 | 39.544 | 1.00 | 18.13 | B | C |
| ATOM | 1729 | OG | SER | B | 322 | 44.695 | 74.242 | 38.557 | 1.00 | 18.46 | B | O |
| ATOM | 1730 | C | SER | B | 322 | 47.021 | 75.746 | 37.854 | 1.00 | 26.55 | B | C |
| ATOM | 1731 | O | SER | B | 322 | 48.167 | 75.356 | 37.597 | 1.00 | 24.35 | B | O |
| ATOM | 1732 | N | TYR | B | 323 | 46.192 | 76.213 | 36.924 | 1.00 | 28.36 | B | N |
| ATOM | 1733 | CA | TYR | B | 323 | 46.598 | 76.274 | 35.528 | 1.00 | 31.57 | B | C |
| ATOM | 1734 | CB | TYR | B | 323 | 45.397 | 76.557 | 34.632 | 1.00 | 32.10 | B | C |
| ATOM | 1735 | CG | TYR | B | 323 | 45.758 | 76.581 | 33.168 | 1.00 | 36.01 | B | C |
| ATOM | 1736 | CD1 | TYR | B | 323 | 45.950 | 77.790 | 32.498 | 1.00 | 37.77 | B | C |
| ATOM | 1737 | CE1 | TYR | B | 323 | 46.270 | 77.824 | 31.139 | 1.00 | 39.71 | B | C |
| ATOM | 1738 | CD2 | TYR | B | 323 | 45.899 | 75.395 | 32.446 | 1.00 | 37.39 | B | C |
| ATOM | 1739 | CE2 | TYR | B | 323 | 46.219 | 75.411 | 31.087 | 1.00 | 39.19 | B | C |
| ATOM | 1740 | CZ | TYR | B | 323 | 46.402 | 76.632 | 30.441 | 1.00 | 41.89 | B | C |
| ATOM | 1741 | OH | TYR | B | 323 | 46.702 | 76.667 | 29.096 | 1.00 | 45.30 | B | O |
| ATOM | 1742 | C | TYR | B | 323 | 47.650 | 77.357 | 35.316 | 1.00 | 32.01 | B | C |
| ATOM | 1743 | O | TYR | B | 323 | 48.551 | 77.217 | 34.489 | 1.00 | 30.55 | B | O |
| ATOM | 1744 | N | GLN | B | 324 | 47.533 | 78.440 | 36.068 | 1.00 | 31.63 | B | N |
| ATOM | 1745 | CA | GLN | B | 324 | 48.482 | 79.533 | 35.939 | 1.00 | 33.97 | B | C |
| ATOM | 1746 | CB | GLN | B | 324 | 48.043 | 80.722 | 36.796 | 1.00 | 35.43 | B | C |
| ATOM | 1747 | CG | GLN | B | 324 | 49.051 | 81.850 | 36.876 | 1.00 | 40.05 | B | C |
| ATOM | 1748 | CD | GLN | B | 324 | 48.901 | 82.667 | 38.155 | 1.00 | 45.11 | B | C |
| ATOM | 1749 | OE1 | GLN | B | 324 | 47.854 | 83.276 | 38.399 | 1.00 | 46.20 | B | O |
| ATOM | 1750 | NE2 | GLN | B | 324 | 49.946 | 82.680 | 38.980 | 1.00 | 45.54 | B | N |
| ATOM | 1751 | C | GLN | B | 324 | 49.866 | 79.082 | 36.361 | 1.00 | 32.59 | B | C |
| ATOM | 1752 | O | GLN | B | 324 | 50.862 | 79.475 | 35.763 | 1.00 | 32.96 | B | O |
| ATOM | 1753 | N | VAL | B | 325 | 49.931 | 78.235 | 37.382 | 1.00 | 32.16 | B | N |
| ATOM | 1754 | CA | VAL | B | 325 | 51.220 | 77.777 | 37.871 | 1.00 | 29.10 | B | C |
| ATOM | 1755 | CB | VAL | B | 325 | 51.324 | 77.973 | 39.405 | 1.00 | 26.61 | B | C |
| ATOM | 1756 | CG1 | VAL | B | 325 | 50.636 | 79.252 | 39.808 | 1.00 | 26.22 | B | C |
| ATOM | 1757 | CG2 | VAL | B | 325 | 50.699 | 76.803 | 40.128 | 1.00 | 29.99 | B | C |
| ATOM | 1758 | C | VAL | B | 325 | 51.653 | 76.346 | 37.536 | 1.00 | 28.28 | B | C |
| ATOM | 1759 | O | VAL | B | 325 | 52.823 | 76.027 | 37.704 | 1.00 | 29.34 | B | O |
| ATOM | 1760 | N | ASP | B | 326 | 50.749 | 75.489 | 37.062 | 1.00 | 26.19 | B | N |
| ATOM | 1761 | CA | ASP | B | 326 | 51.131 | 74.107 | 36.761 | 1.00 | 22.24 | B | C |
| ATOM | 1762 | CB | ASP | B | 326 | 50.494 | 73.151 | 37.772 | 1.00 | 22.93 | B | C |
| ATOM | 1763 | CG | ASP | B | 326 | 51.189 | 73.151 | 39.117 | 1.00 | 21.33 | B | C |
| ATOM | 1764 | OD1 | ASP | B | 326 | 52.241 | 73.800 | 39.264 | 1.00 | 20.53 | B | O |
| ATOM | 1765 | OD2 | ASP | B | 326 | 50.670 | 72.487 | 40.036 | 1.00 | 20.38 | B | O |
| ATOM | 1766 | C | ASP | B | 326 | 50.723 | 73.634 | 35.384 | 1.00 | 21.44 | B | C |
| ATOM | 1767 | O | ASP | B | 326 | 50.691 | 72.434 | 35.145 | 1.00 | 24.18 | B | O |
| ATOM | 1768 | N | ALA | B | 327 | 50.402 | 74.551 | 34.482 | 1.00 | 22.20 | B | N |
| ATOM | 1769 | CA | ALA | B | 327 | 49.950 | 74.164 | 33.142 | 1.00 | 25.46 | B | C |
| ATOM | 1770 | CB | ALA | B | 327 | 49.875 | 75.394 | 32.242 | 1.00 | 24.18 | B | C |
| ATOM | 1771 | C | ALA | B | 327 | 50.825 | 73.099 | 32.492 | 1.00 | 25.60 | B | C |
| ATOM | 1772 | O | ALA | B | 327 | 50.350 | 72.264 | 31.706 | 1.00 | 25.86 | B | O |
| ATOM | 1773 | N | ASP | B | 328 | 52.104 | 73.127 | 32.837 | 1.00 | 27.70 | B | N |
| ATOM | 1774 | CA | ASP | B | 328 | 53.048 | 72.176 | 32.280 | 1.00 | 31.73 | B | C |
| ATOM | 1775 | CB | ASP | B | 328 | 54.317 | 72.904 | 31.822 | 1.00 | 36.48 | B | C |
| ATOM | 1776 | CG | ASP | B | 328 | 54.075 | 73.839 | 30.634 | 1.00 | 39.16 | B | C |
| ATOM | 1777 | OD1 | ASP | B | 328 | 53.181 | 73.570 | 29.793 | 1.00 | 41.44 | B | O |
| ATOM | 1778 | OD2 | ASP | B | 328 | 54.798 | 74.850 | 30.547 | 1.00 | 41.53 | B | O |
| ATOM | 1779 | C | ASP | B | 328 | 53.441 | 71.035 | 33.216 | 1.00 | 30.93 | B | C |
| ATOM | 1780 | O | ASP | B | 328 | 54.365 | 70.291 | 32.907 | 1.00 | 31.58 | B | O |
| ATOM | 1781 | N | ARG | B | 329 | 52.755 | 70.892 | 34.348 | 1.00 | 28.98 | B | N |
| ATOM | 1782 | CA | ARG | B | 329 | 53.070 | 69.818 | 35.282 | 1.00 | 25.56 | B | C |
| ATOM | 1783 | CB | ARG | B | 329 | 52.548 | 70.158 | 36.684 | 1.00 | 28.49 | B | C |
| ATOM | 1784 | CG | ARG | B | 329 | 53.393 | 69.592 | 37.817 | 1.00 | 29.70 | B | C |
| ATOM | 1785 | CD | ARG | B | 329 | 52.605 | 68.710 | 38.784 | 1.00 | 30.75 | B | C |
| ATOM | 1786 | NE | ARG | B | 329 | 52.067 | 69.493 | 39.886 | 1.00 | 31.02 | B | N |
| ATOM | 1787 | CZ | ARG | B | 329 | 52.037 | 69.114 | 41.159 | 1.00 | 30.57 | B | C |
| ATOM | 1788 | NH1 | ARG | B | 329 | 52.519 | 67.947 | 41.540 | 1.00 | 32.69 | B | N |
| ATOM | 1789 | NH2 | ARG | B | 329 | 51.488 | 69.911 | 42.057 | 1.00 | 29.17 | B | N |
| ATOM | 1790 | C | ARG | B | 329 | 52.396 | 68.553 | 34.790 | 1.00 | 23.08 | B | C |
| ATOM | 1791 | O | ARG | B | 329 | 51.251 | 68.610 | 34.322 | 1.00 | 20.32 | B | O |
| ATOM | 1792 | N | VAL | B | 330 | 53.094 | 67.418 | 34.864 | 1.00 | 22.22 | B | N |
| ATOM | 1793 | CA | VAL | B | 330 | 52.454 | 66.171 | 34.445 | 1.00 | 24.80 | B | C |
| ATOM | 1794 | CB | VAL | B | 330 | 53.446 | 65.014 | 34.292 | 1.00 | 23.18 | B | C |
| ATOM | 1795 | CG1 | VAL | B | 330 | 52.682 | 63.712 | 34.001 | 1.00 | 20.41 | B | C |
| ATOM | 1796 | CG2 | VAL | B | 330 | 54.403 | 65.326 | 33.165 | 1.00 | 21.64 | B | C |
| ATOM | 1797 | C | VAL | B | 330 | 51.500 | 65.908 | 35.593 | 1.00 | 26.33 | B | C |
| ATOM | 1798 | O | VAL | B | 330 | 51.902 | 65.888 | 36.759 | 1.00 | 25.60 | B | O |
| ATOM | 1799 | N | VAL | B | 331 | 50.240 | 65.688 | 35.268 | 1.00 | 27.00 | B | N |
| ATOM | 1800 | CA | VAL | B | 331 | 49.264 | 65.561 | 36.321 | 1.00 | 30.04 | B | C |
| ATOM | 1801 | CB | VAL | B | 331 | 48.545 | 66.933 | 36.443 | 1.00 | 29.37 | B | C |
| ATOM | 1802 | CG1 | VAL | B | 331 | 47.288 | 66.954 | 35.582 | 1.00 | 23.68 | B | C |
| ATOM | 1803 | CG2 | VAL | B | 331 | 48.270 | 67.252 | 37.884 | 1.00 | 34.06 | B | C |
| ATOM | 1804 | C | VAL | B | 331 | 48.263 | 64.443 | 36.120 | 1.00 | 31.71 | B | C |
| ATOM | 1805 | O | VAL | B | 331 | 47.523 | 64.090 | 37.037 | 1.00 | 31.26 | B | O |
| ATOM | 1806 | N | TYR | B | 332 | 48.259 | 63.872 | 34.922 | 1.00 | 33.05 | B | N |
| ATOM | 1807 | CA | TYR | B | 332 | 47.312 | 62.821 | 34.584 | 1.00 | 36.84 | B | C |
| ATOM | 1808 | CB | TYR | B | 332 | 46.168 | 63.450 | 33.790 | 1.00 | 32.88 | B | C |
| ATOM | 1809 | CG | TYR | B | 332 | 45.151 | 62.498 | 33.227 | 1.00 | 34.50 | B | C |
| ATOM | 1810 | CD1 | TYR | B | 332 | 44.014 | 62.139 | 33.958 | 1.00 | 35.19 | B | C |
| ATOM | 1811 | CE1 | TYR | B | 332 | 43.031 | 61.312 | 33.403 | 1.00 | 37.12 | B | C |
| ATOM | 1812 | CD2 | TYR | B | 332 | 45.285 | 62.005 | 31.933 | 1.00 | 36.37 | B | C |
| ATOM | 1813 | CE2 | TYR | B | 332 | 44.311 | 61.180 | 31.370 | 1.00 | 38.34 | B | C |
| ATOM | 1814 | CZ | TYR | B | 332 | 43.187 | 60.840 | 32.105 | 1.00 | 38.93 | B | C |
| ATOM | 1815 | OH | TYR | B | 332 | 42.212 | 60.050 | 31.530 | 1.00 | 43.80 | B | O |
| ATOM | 1816 | C | TYR | B | 332 | 48.029 | 61.752 | 33.772 | 1.00 | 41.54 | B | C |
| ATOM | 1817 | O | TYR | B | 332 | 48.945 | 62.058 | 33.010 | 1.00 | 41.75 | B | O |
| ATOM | 1818 | N | SER | B | 333 | 47.619 | 60.498 | 33.920 | 1.00 | 45.30 | B | N |
| ATOM | 1819 | CA | SER | B | 333 | 48.286 | 59.427 | 33.192 | 1.00 | 47.41 | B | C |
| ATOM | 1820 | CB | SER | B | 333 | 48.721 | 58.322 | 34.157 | 1.00 | 47.17 | B | C |
| ATOM | 1821 | OG | SER | B | 333 | 49.456 | 57.326 | 33.473 | 1.00 | 44.73 | B | O |
| ATOM | 1822 | C | SER | B | 333 | 47.477 | 58.805 | 32.070 | 1.00 | 49.78 | B | C |
| ATOM | 1823 | O | SER | B | 333 | 46.337 | 58.381 | 32.266 | 1.00 | 50.00 | B | O |
| ATOM | 1824 | N | THR | B | 334 | 48.082 | 58.767 | 30.888 | 1.00 | 50.65 | B | N |
| ATOM | 1825 | CA | THR | B | 334 | 47.467 | 58.148 | 29.725 | 1.00 | 53.58 | B | C |
| ATOM | 1826 | CB | THR | B | 334 | 46.956 | 59.188 | 28.717 | 1.00 | 53.59 | B | C |
| ATOM | 1827 | OG1 | THR | B | 334 | 45.538 | 59.034 | 28.584 | 1.00 | 55.41 | B | O |
| ATOM | 1828 | CG2 | THR | B | 334 | 47.606 | 58.995 | 27.347 | 1.00 | 52.42 | B | C |
| ATOM | 1829 | C | THR | B | 334 | 48.528 | 57.265 | 29.078 | 1.00 | 55.45 | B | C |
| ATOM | 1830 | O | THR | B | 334 | 49.704 | 57.630 | 29.034 | 1.00 | 54.03 | B | O |
| ATOM | 1831 | N | LYS | B | 335 | 48.106 | 56.108 | 28.577 | 1.00 | 57.30 | B | N |
| ATOM | 1832 | CA | LYS | B | 335 | 49.023 | 55.148 | 27.964 | 1.00 | 58.99 | B | C |
| ATOM | 1833 | CB | LYS | B | 335 | 48.260 | 54.185 | 27.061 | 1.00 | 56.35 | B | C |
| ATOM | 1834 | CG | LYS | B | 335 | 48.844 | 52.775 | 27.077 | 1.00 | 56.34 | B | C |
| ATOM | 1835 | CD | LYS | B | 335 | 50.333 | 52.720 | 26.712 | 1.00 | 52.41 | B | C |
| ATOM | 1836 | CE | LYS | B | 335 | 51.132 | 51.940 | 27.753 | 1.00 | 51.52 | B | C |
| ATOM | 1837 | NZ | LYS | B | 335 | 52.098 | 50.961 | 27.165 | 1.00 | 50.42 | B | N |
| ATOM | 1838 | C | LYS | B | 335 | 50.221 | 55.697 | 27.188 | 1.00 | 60.14 | B | C |
| ATOM | 1839 | O | LYS | B | 335 | 51.353 | 55.703 | 27.691 | 1.00 | 61.55 | B | O |
| ATOM | 1840 | N | GLU | B | 336 | 49.979 | 56.132 | 25.957 | 1.00 | 59.63 | B | N |
| ATOM | 1841 | CA | GLU | B | 336 | 51.053 | 56.650 | 25.122 | 1.00 | 59.75 | B | C |
| ATOM | 1842 | CB | GLU | B | 336 | 50.530 | 56.979 | 23.716 | 1.00 | 62.38 | B | C |
| ATOM | 1843 | CG | GLU | B | 336 | 51.314 | 56.307 | 22.560 | 1.00 | 64.46 | B | C |
| ATOM | 1844 | CD | GLU | B | 336 | 52.388 | 55.310 | 23.028 | 1.00 | 66.24 | B | C |
| ATOM | 1845 | OE1 | GLU | B | 336 | 53.554 | 55.727 | 23.245 | 1.00 | 67.48 | B | O |
| ATOM | 1846 | OE2 | GLU | B | 336 | 52.067 | 54.108 | 23.175 | 1.00 | 64.67 | B | O |
| ATOM | 1847 | C | GLU | B | 336 | 51.732 | 57.874 | 25.722 | 1.00 | 58.56 | B | C |
| ATOM | 1848 | O | GLU | B | 336 | 52.887 | 58.171 | 25.396 | 1.00 | 58.27 | B | O |
| ATOM | 1849 | N | LYS | B | 337 | 51.024 | 58.578 | 26.603 | 1.00 | 57.14 | B | N |
| ATOM | 1850 | CA | LYS | B | 337 | 51.594 | 59.769 | 27.225 | 1.00 | 53.72 | B | C |
| ATOM | 1851 | CB | LYS | B | 337 | 51.687 | 60.888 | 26.186 | 1.00 | 53.52 | B | C |
| ATOM | 1852 | CG | LYS | B | 337 | 52.344 | 62.152 | 26.680 | 1.00 | 52.68 | B | C |
| ATOM | 1853 | CD | LYS | B | 337 | 52.169 | 63.275 | 25.674 | 1.00 | 51.94 | B | C |
| ATOM | 1854 | CE | LYS | B | 337 | 52.549 | 64.613 | 26.286 | 1.00 | 54.76 | B | C |
| ATOM | 1855 | NZ | LYS | B | 337 | 53.858 | 65.132 | 25.784 | 1.00 | 53.04 | B | N |
| ATOM | 1856 | C | LYS | B | 337 | 50.833 | 60.271 | 28.449 | 1.00 | 51.52 | B | C |
| ATOM | 1857 | O | LYS | B | 337 | 49.603 | 60.379 | 28.445 | 1.00 | 52.27 | B | O |
| ATOM | 1858 | N | ASN | B | 338 | 51.579 | 60.570 | 29.504 | 1.00 | 47.78 | B | N |
| ATOM | 1859 | CA | ASN | B | 338 | 50.970 | 61.094 | 30.711 | 1.00 | 44.94 | B | C |
| ATOM | 1860 | CB | ASN | B | 338 | 51.911 | 60.924 | 31.907 | 1.00 | 44.75 | B | C |
| ATOM | 1861 | CG | ASN | B | 338 | 52.338 | 59.479 | 32.116 | 1.00 | 40.30 | B | C |
| ATOM | 1862 | OD1 | ASN | B | 338 | 51.506 | 58.589 | 32.307 | 1.00 | 41.54 | B | O |
| ATOM | 1863 | ND2 | ASN | B | 338 | 53.642 | 59.242 | 32.080 | 1.00 | 37.33 | B | N |
| ATOM | 1864 | C | ASN | B | 338 | 50.775 | 62.565 | 30.368 | 1.00 | 42.16 | B | C |
| ATOM | 1865 | O | ASN | B | 338 | 51.693 | 63.220 | 29.882 | 1.00 | 39.80 | B | O |
| ATOM | 1866 | N | LEU | B | 339 | 49.576 | 63.078 | 30.606 | 1.00 | 39.42 | B | N |
| ATOM | 1867 | CA | LEU | B | 339 | 49.272 | 64.457 | 30.262 | 1.00 | 36.44 | B | C |
| ATOM | 1868 | CB | LEU | B | 339 | 47.765 | 64.608 | 30.009 | 1.00 | 36.31 | B | C |
| ATOM | 1869 | CG | LEU | B | 339 | 47.142 | 63.477 | 29.206 | 1.00 | 36.18 | B | C |
| ATOM | 1870 | CD1 | LEU | B | 339 | 45.648 | 63.708 | 29.029 | 1.00 | 36.40 | B | C |
| ATOM | 1871 | CD2 | LEU | B | 339 | 47.862 | 63.405 | 27.871 | 1.00 | 33.76 | B | C |
| ATOM | 1872 | C | LEU | B | 339 | 49.687 | 65.496 | 31.283 | 1.00 | 34.99 | B | C |
| ATOM | 1873 | O | LEU | B | 339 | 49.766 | 65.230 | 32.487 | 1.00 | 33.93 | B | O |
| ATOM | 1874 | N | THR | B | 340 | 49.965 | 66.693 | 30.785 | 1.00 | 31.86 | B | N |
| ATOM | 1875 | CA | THR | B | 340 | 50.284 | 67.800 | 31.665 | 1.00 | 29.18 | B | C |
| ATOM | 1876 | CB | THR | B | 340 | 51.210 | 68.817 | 30.998 | 1.00 | 29.32 | B | C |
| ATOM | 1877 | OG1 | THR | B | 340 | 50.510 | 69.506 | 29.953 | 1.00 | 32.09 | B | O |
| ATOM | 1878 | CG2 | THR | B | 340 | 52.406 | 68.118 | 30.426 | 1.00 | 31.09 | B | C |
| ATOM | 1879 | C | THR | B | 340 | 48.921 | 68.445 | 31.915 | 1.00 | 27.33 | B | C |
| ATOM | 1880 | O | THR | B | 340 | 47.936 | 68.087 | 31.256 | 1.00 | 24.34 | B | O |
| ATOM | 1881 | N | LEU | B | 341 | 48.847 | 69.374 | 32.866 | 1.00 | 27.05 | B | N |
| ATOM | 1882 | CA | LEU | B | 341 | 47.566 | 70.018 | 33.159 | 1.00 | 27.12 | B | C |
| ATOM | 1883 | CB | LEU | B | 341 | 47.762 | 71.130 | 34.196 | 1.00 | 24.40 | B | C |
| ATOM | 1884 | CG | LEU | B | 341 | 46.501 | 71.792 | 34.772 | 1.00 | 26.92 | B | C |
| ATOM | 1885 | CD1 | LEU | B | 341 | 45.501 | 70.725 | 35.248 | 1.00 | 25.28 | B | C |
| ATOM | 1886 | CD2 | LEU | B | 341 | 46.901 | 72.736 | 35.905 | 1.00 | 18.18 | B | C |
| ATOM | 1887 | C | LEU | B | 341 | 46.973 | 70.582 | 31.861 | 1.00 | 26.19 | B | C |
| ATOM | 1888 | O | LEU | B | 341 | 45.807 | 70.342 | 31.523 | 1.00 | 24.44 | B | O |
| ATOM | 1889 | N | LYS | B | 342 | 47.808 | 71.304 | 31.123 | 1.00 | 25.98 | B | N |
| ATOM | 1890 | CA | LYS | B | 342 | 47.405 | 71.905 | 29.864 | 1.00 | 26.94 | B | C |
| ATOM | 1891 | CB | LYS | B | 342 | 48.594 | 72.585 | 29.221 | 1.00 | 31.30 | B | C |
| ATOM | 1892 | CG | LYS | B | 342 | 48.245 | 73.455 | 28.045 | 1.00 | 34.10 | B | C |
| ATOM | 1893 | CD | LYS | B | 342 | 49.482 | 74.227 | 27.605 | 1.00 | 37.61 | B | C |
| ATOM | 1894 | CE | LYS | B | 342 | 49.194 | 75.709 | 27.444 | 1.00 | 42.44 | B | C |
| ATOM | 1895 | NZ | LYS | B | 342 | 49.853 | 76.532 | 28.510 | 1.00 | 44.68 | B | N |
| ATOM | 1896 | C | LYS | B | 342 | 46.842 | 70.893 | 28.898 | 1.00 | 26.47 | B | C |
| ATOM | 1897 | O | LYS | B | 342 | 45.820 | 71.147 | 28.270 | 1.00 | 25.42 | B | O |
| ATOM | 1898 | N | GLN | B | 343 | 47.505 | 69.744 | 28.783 | 1.00 | 26.85 | B | N |
| ATOM | 1899 | CA | GLN | B | 343 | 47.055 | 68.694 | 27.876 | 1.00 | 27.08 | B | C |
| ATOM | 1900 | CB | GLN | B | 343 | 48.118 | 67.611 | 27.747 | 1.00 | 28.72 | B | C |
| ATOM | 1901 | CG | GLN | B | 343 | 49.327 | 68.030 | 26.956 | 1.00 | 28.55 | B | C |
| ATOM | 1902 | CD | GLN | B | 343 | 50.491 | 67.084 | 27.159 | 1.00 | 34.41 | B | C |
| ATOM | 1903 | OE1 | GLN | B | 343 | 50.314 | 65.933 | 27.583 | 1.00 | 39.67 | B | O |
| ATOM | 1904 | NE2 | GLN | B | 343 | 51.689 | 67.561 | 26.861 | 1.00 | 33.14 | B | N |
| ATOM | 1905 | C | GLN | B | 343 | 45.753 | 68.045 | 28.298 | 1.00 | 27.07 | B | C |
| ATOM | 1906 | O | GLN | B | 343 | 44.945 | 67.664 | 27.439 | 1.00 | 27.63 | B | O |
| ATOM | 1907 | N | LEU | B | 344 | 45.550 | 67.899 | 29.609 | 1.00 | 25.63 | B | N |
| ATOM | 1908 | CA | LEU | B | 344 | 44.325 | 67.282 | 30.089 | 1.00 | 24.64 | B | C |
| ATOM | 1909 | CB | LEU | B | 344 | 44.374 | 67.055 | 31.611 | 1.00 | 23.68 | B | C |
| ATOM | 1910 | CG | LEU | B | 344 | 43.024 | 66.671 | 32.238 | 1.00 | 22.49 | B | C |
| ATOM | 1911 | CD1 | LEU | B | 344 | 42.574 | 65.313 | 31.722 | 1.00 | 21.16 | B | C |
| ATOM | 1912 | CD2 | LEU | B | 344 | 43.151 | 66.664 | 33.762 | 1.00 | 25.39 | B | C |
| ATOM | 1913 | C | LEU | B | 344 | 43.165 | 68.194 | 29.722 | 1.00 | 23.42 | B | C |
| ATOM | 1914 | O | LEU | B | 344 | 42.088 | 67.724 | 29.344 | 1.00 | 25.56 | B | O |
| ATOM | 1915 | N | PHE | B | 345 | 43.388 | 69.500 | 29.824 | 1.00 | 23.70 | B | N |
| ATOM | 1916 | CA | PHE | B | 345 | 42.329 | 70.450 | 29.498 | 1.00 | 27.32 | B | C |
| ATOM | 1917 | CB | PHE | B | 345 | 42.683 | 71.850 | 30.006 | 1.00 | 26.89 | B | C |
| ATOM | 1918 | CG | PHE | B | 345 | 42.310 | 72.076 | 31.457 | 1.00 | 26.51 | B | C |
| ATOM | 1919 | CD1 | PHE | B | 345 | 40.987 | 71.948 | 31.881 | 1.00 | 27.35 | B | C |
| ATOM | 1920 | CD2 | PHE | B | 345 | 43.286 | 72.374 | 32.401 | 1.00 | 25.08 | B | C |
| ATOM | 1921 | CE1 | PHE | B | 345 | 40.647 | 72.111 | 33.228 | 1.00 | 25.06 | B | C |
| ATOM | 1922 | CE2 | PHE | B | 345 | 42.954 | 72.537 | 33.747 | 1.00 | 26.73 | B | C |
| ATOM | 1923 | CZ | PHE | B | 345 | 41.632 | 72.404 | 34.157 | 1.00 | 23.81 | B | C |
| ATOM | 1924 | C | PHE | B | 345 | 42.062 | 70.453 | 28.000 | 1.00 | 28.40 | B | C |
| ATOM | 1925 | O | PHE | B | 345 | 40.922 | 70.640 | 27.560 | 1.00 | 28.65 | B | O |
| ATOM | 1926 | N | ASP | B | 346 | 43.113 | 70.236 | 27.214 | 1.00 | 31.72 | B | N |
| ATOM | 1927 | CA | ASP | B | 346 | 42.969 | 70.149 | 25.761 | 1.00 | 32.12 | B | C |
| ATOM | 1928 | CB | ASP | B | 346 | 44.320 | 69.973 | 25.095 | 1.00 | 36.97 | B | C |
| ATOM | 1929 | CG | ASP | B | 346 | 45.087 | 71.250 | 25.003 | 1.00 | 41.34 | B | C |
| ATOM | 1930 | OD1 | ASP | B | 346 | 44.623 | 72.263 | 25.560 | 1.00 | 48.57 | B | O |
| ATOM | 1931 | OD2 | ASP | B | 346 | 46.166 | 71.246 | 24.375 | 1.00 | 48.77 | B | O |
| ATOM | 1932 | C | ASP | B | 346 | 42.134 | 68.911 | 25.459 | 1.00 | 31.56 | B | C |
| ATOM | 1933 | O | ASP | B | 346 | 41.170 | 68.964 | 24.701 | 1.00 | 31.05 | B | O |
| ATOM | 1934 | N | LYS | B | 347 | 42.528 | 67.792 | 26.054 | 1.00 | 30.72 | B | N |
| ATOM | 1935 | CA | LYS | B | 347 | 41.812 | 66.541 | 25.867 | 1.00 | 32.52 | B | C |
| ATOM | 1936 | CB | LYS | B | 347 | 42.451 | 65.440 | 26.724 | 1.00 | 35.78 | B | C |
| ATOM | 1937 | CG | LYS | B | 347 | 41.764 | 64.080 | 26.655 | 1.00 | 40.10 | B | C |
| ATOM | 1938 | CD | LYS | B | 347 | 40.797 | 63.882 | 27.827 | 1.00 | 46.96 | B | C |
| ATOM | 1939 | CE | LYS | B | 347 | 41.108 | 62.623 | 28.644 | 1.00 | 48.28 | B | C |
| ATOM | 1940 | NZ | LYS | B | 347 | 41.448 | 61.452 | 27.784 | 1.00 | 50.10 | B | N |
| ATOM | 1941 | C | LYS | B | 347 | 40.356 | 66.725 | 26.260 | 1.00 | 32.29 | B | C |
| ATOM | 1942 | O | LYS | B | 347 | 39.476 | 66.066 | 25.706 | 1.00 | 34.72 | B | O |
| ATOM | 1943 | N | LEU | B | 348 | 40.106 | 67.617 | 27.219 | 1.00 | 32.70 | B | N |
| ATOM | 1944 | CA | LEU | B | 348 | 38.752 | 67.881 | 27.702 | 1.00 | 30.66 | B | C |
| ATOM | 1945 | CB | LEU | B | 348 | 38.784 | 68.313 | 29.167 | 1.00 | 29.25 | B | C |
| ATOM | 1946 | CG | LEU | B | 348 | 39.078 | 67.215 | 30.191 | 1.00 | 27.39 | B | C |
| ATOM | 1947 | CD1 | LEU | B | 348 | 39.114 | 67.854 | 31.565 | 1.00 | 23.63 | B | C |
| ATOM | 1948 | CD2 | LEU | B | 348 | 38.022 | 66.096 | 30.121 | 1.00 | 24.45 | B | C |
| ATOM | 1949 | C | LEU | B | 348 | 38.071 | 68.954 | 26.879 | 1.00 | 31.25 | B | C |
| ATOM | 1950 | O | LEU | B | 348 | 36.864 | 69.156 | 26.987 | 1.00 | 32.65 | B | O |
| ATOM | 1951 | N | LYS | B | 349 | 38.858 | 69.649 | 26.068 | 1.00 | 33.25 | B | N |
| ATOM | 1952 | CA | LYS | B | 349 | 38.346 | 70.703 | 25.197 | 1.00 | 36.65 | B | C |
| ATOM | 1953 | CB | LYS | B | 349 | 37.182 | 70.148 | 24.344 | 1.00 | 41.35 | B | C |
| ATOM | 1954 | CG | LYS | B | 349 | 36.259 | 71.184 | 23.679 | 1.00 | 48.86 | B | C |
| ATOM | 1955 | CD | LYS | B | 349 | 34.846 | 71.211 | 24.326 | 1.00 | 51.50 | B | C |
| ATOM | 1956 | CE | LYS | B | 349 | 34.230 | 72.613 | 24.295 | 1.00 | 52.20 | B | C |
| ATOM | 1957 | NZ | LYS | B | 349 | 34.377 | 73.281 | 22.957 | 1.00 | 52.40 | B | N |
| ATOM | 1958 | C | LYS | B | 349 | 37.913 | 71.929 | 26.001 | 1.00 | 35.77 | B | C |
| ATOM | 1959 | O | LYS | B | 349 | 36.836 | 72.490 | 25.778 | 1.00 | 34.82 | B | O |
| ATOM | 1960 | N | LEU | B | 350 | 38.753 | 72.355 | 26.943 | 1.00 | 32.72 | B | N |
| ATOM | 1961 | CA | LEU | B | 350 | 38.409 | 73.523 | 27.744 | 1.00 | 30.66 | B | C |
| ATOM | 1962 | CB | LEU | B | 350 | 37.773 | 73.116 | 29.078 | 1.00 | 29.41 | B | C |
| ATOM | 1963 | CG | LEU | B | 350 | 36.872 | 71.892 | 29.222 | 1.00 | 31.39 | B | C |
| ATOM | 1964 | CD1 | LEU | B | 350 | 37.011 | 71.307 | 30.628 | 1.00 | 29.99 | B | C |
| ATOM | 1965 | CD2 | LEU | B | 350 | 35.427 | 72.306 | 28.945 | 1.00 | 32.34 | B | C |
| ATOM | 1966 | C | LEU | B | 350 | 39.589 | 74.399 | 28.069 | 1.00 | 29.23 | B | C |
| ATOM | 1967 | O | LEU | B | 350 | 40.720 | 73.942 | 28.113 | 1.00 | 30.35 | B | O |
| ATOM | 1968 | N | HIS | B | 351 | 39.331 | 75.681 | 28.266 | 1.00 | 31.01 | B | N |
| ATOM | 1969 | CA | HIS | B | 351 | 40.398 | 76.548 | 28.708 | 1.00 | 31.84 | B | C |
| ATOM | 1970 | CB | HIS | B | 351 | 40.671 | 77.731 | 27.805 | 1.00 | 34.28 | B | C |
| ATOM | 1971 | CG | HIS | B | 351 | 41.896 | 78.479 | 28.224 | 1.00 | 38.67 | B | C |
| ATOM | 1972 | CD2 | HIS | B | 351 | 42.097 | 79.355 | 29.239 | 1.00 | 39.86 | B | C |
| ATOM | 1973 | ND1 | HIS | B | 351 | 43.139 | 78.233 | 27.680 | 1.00 | 40.25 | B | N |
| ATOM | 1974 | CE1 | HIS | B | 351 | 44.053 | 78.922 | 28.344 | 1.00 | 40.52 | B | C |
| ATOM | 1975 | NE2 | HIS | B | 351 | 43.447 | 79.611 | 29.295 | 1.00 | 40.63 | B | N |
| ATOM | 1976 | C | HIS | B | 351 | 39.950 | 77.067 | 30.057 | 1.00 | 32.19 | B | C |
| ATOM | 1977 | O | HIS | B | 351 | 39.000 | 77.842 | 30.155 | 1.00 | 33.99 | B | O |
| ATOM | 1978 | N | PRO | B | 352 | 40.638 | 76.645 | 31.119 | 1.00 | 30.71 | B | N |
| ATOM | 1979 | CD | PRO | B | 352 | 41.807 | 75.755 | 31.068 | 1.00 | 30.49 | B | C |
| ATOM | 1980 | CA | PRO | B | 352 | 40.323 | 77.045 | 32.487 | 1.00 | 30.71 | B | C |
| ATOM | 1981 | CB | PRO | B | 352 | 41.592 | 76.705 | 33.275 | 1.00 | 31.06 | B | C |
| ATOM | 1982 | CG | PRO | B | 352 | 42.580 | 76.167 | 32.268 | 1.00 | 31.28 | B | C |
| ATOM | 1983 | C | PRO | B | 352 | 39.913 | 78.499 | 32.659 | 1.00 | 30.80 | B | C |
| ATOM | 1984 | O | PRO | B | 352 | 39.001 | 78.798 | 33.431 | 1.00 | 33.48 | B | O |
| ATOM | 1985 | N | TYR | B | 353 | 40.554 | 79.403 | 31.930 | 1.00 | 28.32 | B | N |
| ATOM | 1986 | CA | TYR | B | 353 | 40.242 | 80.813 | 32.083 | 1.00 | 27.52 | B | C |
| ATOM | 1987 | CB | TYR | B | 353 | 41.324 | 81.655 | 31.419 | 1.00 | 29.35 | B | C |
| ATOM | 1988 | CG | TYR | B | 353 | 42.666 | 81.516 | 32.106 | 1.00 | 33.62 | B | C |
| ATOM | 1989 | CD1 | TYR | B | 353 | 42.775 | 80.898 | 33.362 | 1.00 | 33.11 | B | C |
| ATOM | 1990 | CE1 | TYR | B | 353 | 44.018 | 80.754 | 33.995 | 1.00 | 33.03 | B | C |
| ATOM | 1991 | CD2 | TYR | B | 353 | 43.834 | 81.989 | 31.503 | 1.00 | 34.28 | B | C |
| ATOM | 1992 | CE2 | TYR | B | 353 | 45.083 | 81.850 | 32.128 | 1.00 | 34.09 | B | C |
| ATOM | 1993 | CZ | TYR | B | 353 | 45.167 | 81.233 | 33.368 | 1.00 | 34.17 | B | C |
| ATOM | 1994 | OH | TYR | B | 353 | 46.401 | 81.097 | 33.968 | 1.00 | 34.18 | B | O |
| ATOM | 1995 | C | TYR | B | 353 | 38.861 | 81.233 | 31.602 | 1.00 | 26.65 | B | C |
| ATOM | 1996 | O | TYR | B | 353 | 38.360 | 82.281 | 32.011 | 1.00 | 26.03 | B | O |
| ATOM | 1997 | N | ASP | B | 354 | 38.236 | 80.421 | 30.757 | 1.00 | 23.90 | B | N |
| ATOM | 1998 | CA | ASP | B | 354 | 36.900 | 80.748 | 30.267 | 1.00 | 24.89 | B | C |
| ATOM | 1999 | CB | ASP | B | 354 | 36.669 | 80.192 | 28.858 | 1.00 | 28.55 | B | C |
| ATOM | 2000 | CG | ASP | B | 354 | 37.740 | 80.611 | 27.880 | 1.00 | 34.34 | B | C |
| ATOM | 2001 | OD1 | ASP | B | 354 | 38.283 | 81.730 | 28.011 | 1.00 | 33.03 | B | O |
| ATOM | 2002 | OD2 | ASP | B | 354 | 38.038 | 79.806 | 26.974 | 1.00 | 39.79 | B | O |
| ATOM | 2003 | C | ASP | B | 354 | 35.836 | 80.165 | 31.187 | 1.00 | 22.21 | B | C |
| ATOM | 2004 | O | ASP | B | 354 | 34.646 | 80.430 | 31.017 | 1.00 | 19.39 | B | O |
| ATOM | 2005 | N | LEU | B | 355 | 36.272 | 79.358 | 32.150 | 1.00 | 20.91 | B | N |
| ATOM | 2006 | CA | LEU | B | 355 | 35.349 | 78.726 | 33.084 | 1.00 | 20.07 | B | C |
| ATOM | 2007 | CB | LEU | B | 355 | 36.105 | 77.785 | 34.007 | 1.00 | 16.83 | B | C |
| ATOM | 2008 | CG | LEU | B | 355 | 36.445 | 76.494 | 33.263 | 1.00 | 16.84 | B | C |
| ATOM | 2009 | CD1 | LEU | B | 355 | 37.296 | 75.601 | 34.154 | 1.00 | 17.87 | B | C |
| ATOM | 2010 | CD2 | LEU | B | 355 | 35.155 | 75.793 | 32.837 | 1.00 | 13.70 | B | C |
| ATOM | 2011 | C | LEU | B | 355 | 34.561 | 79.754 | 33.879 | 1.00 | 19.86 | B | C |
| ATOM | 2012 | O | LEU | B | 355 | 35.039 | 80.849 | 34.183 | 1.00 | 17.79 | B | O |
| ATOM | 2013 | N | THR | B | 356 | 33.344 | 79.367 | 34.228 | 1.00 | 19.96 | B | N |
| ATOM | 2014 | CA | THR | B | 356 | 32.413 | 80.234 | 34.925 | 1.00 | 19.12 | B | C |
| ATOM | 2015 | CB | THR | B | 356 | 31.428 | 80.743 | 33.855 | 1.00 | 17.57 | B | C |
| ATOM | 2016 | OG1 | THR | B | 356 | 31.833 | 82.039 | 33.411 | 1.00 | 24.68 | B | O |
| ATOM | 2017 | CG2 | THR | B | 356 | 30.056 | 80.776 | 34.349 | 1.00 | 18.32 | B | C |
| ATOM | 2018 | C | THR | B | 356 | 31.726 | 79.330 | 35.957 | 1.00 | 18.75 | B | C |
| ATOM | 2019 | O | THR | B | 356 | 31.896 | 78.118 | 35.876 | 1.00 | 16.82 | B | O |
| ATOM | 2020 | N | VAL | B | 357 | 30.984 | 79.867 | 36.933 | 1.00 | 17.41 | B | N |
| ATOM | 2021 | CA | VAL | B | 357 | 30.309 | 78.947 | 37.847 | 1.00 | 17.42 | B | C |
| ATOM | 2022 | CB | VAL | B | 357 | 29.639 | 79.628 | 39.111 | 1.00 | 18.29 | B | C |
| ATOM | 2023 | CG1 | VAL | B | 357 | 30.674 | 80.402 | 39.917 | 1.00 | 16.64 | B | C |
| ATOM | 2024 | CG2 | VAL | B | 357 | 28.497 | 80.493 | 38.709 | 1.00 | 19.07 | B | C |
| ATOM | 2025 | C | VAL | B | 357 | 29.238 | 78.230 | 37.022 | 1.00 | 16.44 | B | C |
| ATOM | 2026 | O | VAL | B | 357 | 28.861 | 77.105 | 37.334 | 1.00 | 15.07 | B | O |
| ATOM | 2027 | N | ASP | B | 358 | 28.764 | 78.873 | 35.952 | 1.00 | 15.82 | B | N |
| ATOM | 2028 | CA | ASP | B | 358 | 27.768 | 78.252 | 35.073 | 1.00 | 15.95 | B | C |
| ATOM | 2029 | CB | ASP | B | 358 | 27.309 | 79.222 | 33.978 | 1.00 | 19.04 | B | C |
| ATOM | 2030 | CG | ASP | B | 358 | 26.426 | 80.338 | 34.501 | 1.00 | 20.80 | B | C |
| ATOM | 2031 | OD1 | ASP | B | 358 | 25.777 | 80.165 | 35.560 | 1.00 | 18.84 | B | O |
| ATOM | 2032 | OD2 | ASP | B | 358 | 26.379 | 81.398 | 33.836 | 1.00 | 24.16 | B | O |
| ATOM | 2033 | C | ASP | B | 358 | 28.371 | 77.015 | 34.385 | 1.00 | 15.82 | B | C |
| ATOM | 2034 | O | ASP | B | 358 | 27.770 | 75.941 | 34.380 | 1.00 | 15.49 | B | O |
| ATOM | 2035 | N | SER | B | 359 | 29.548 | 77.171 | 33.787 | 1.00 | 15.85 | B | N |
| ATOM | 2036 | CA | SER | B | 359 | 30.206 | 76.049 | 33.112 | 1.00 | 17.86 | B | C |
| ATOM | 2037 | CB | SER | B | 359 | 31.260 | 76.558 | 32.123 | 1.00 | 15.33 | B | C |
| ATOM | 2038 | OG | SER | B | 359 | 32.072 | 77.554 | 32.711 | 1.00 | 20.88 | B | O |
| ATOM | 2039 | C | SER | B | 359 | 30.827 | 75.053 | 34.110 | 1.00 | 16.98 | B | C |
| ATOM | 2040 | O | SER | B | 359 | 30.930 | 73.871 | 33.809 | 1.00 | 17.18 | B | O |
| ATOM | 2041 | N | LEU | B | 360 | 31.241 | 75.527 | 35.287 | 1.00 | 17.36 | B | N |
| ATOM | 2042 | CA | LEU | B | 360 | 31.779 | 74.638 | 36.327 | 1.00 | 16.98 | B | C |
| ATOM | 2043 | CB | LEU | B | 360 | 32.188 | 75.442 | 37.571 | 1.00 | 17.84 | B | C |
| ATOM | 2044 | CG | LEU | B | 360 | 32.709 | 74.668 | 38.794 | 1.00 | 19.22 | B | C |
| ATOM | 2045 | CD1 | LEU | B | 360 | 33.962 | 73.863 | 38.409 | 1.00 | 16.98 | B | C |
| ATOM | 2046 | CD2 | LEU | B | 360 | 33.043 | 75.659 | 39.924 | 1.00 | 13.36 | B | C |
| ATOM | 2047 | C | LEU | B | 360 | 30.636 | 73.666 | 36.671 | 1.00 | 18.02 | B | C |
| ATOM | 2048 | O | LEU | B | 360 | 30.866 | 72.475 | 36.906 | 1.00 | 16.59 | B | O |
| ATOM | 2049 | N | ASP | B | 361 | 29.411 | 74.195 | 36.717 | 1.00 | 18.74 | B | N |
| ATOM | 2050 | CA | ASP | B | 361 | 28.200 | 73.394 | 36.936 | 1.00 | 21.52 | B | C |
| ATOM | 2051 | CB | ASP | B | 361 | 27.885 | 72.653 | 35.618 | 1.00 | 25.08 | B | C |
| ATOM | 2052 | CG | ASP | B | 361 | 26.421 | 72.227 | 35.490 | 1.00 | 27.71 | B | C |
| ATOM | 2053 | OD1 | ASP | B | 361 | 25.539 | 72.892 | 36.069 | 1.00 | 31.69 | B | O |
| ATOM | 2054 | OD2 | ASP | B | 361 | 26.152 | 71.219 | 34.792 | 1.00 | 27.03 | B | O |
| ATOM | 2055 | C | ASP | B | 361 | 28.229 | 72.390 | 38.107 | 1.00 | 24.98 | B | C |
| ATOM | 2056 | O | ASP | B | 361 | 27.848 | 71.222 | 37.942 | 1.00 | 25.56 | B | O |
| ATOM | 2057 | N | VAL | B | 362 | 28.664 | 72.832 | 39.286 | 1.00 | 25.20 | B | N |
| ATOM | 2058 | CA | VAL | B | 362 | 28.709 | 71.936 | 40.444 | 1.00 | 26.07 | B | C |
| ATOM | 2059 | CB | VAL | B | 362 | 30.086 | 71.992 | 41.166 | 1.00 | 23.24 | B | C |
| ATOM | 2060 | CG1 | VAL | B | 362 | 31.159 | 71.456 | 40.255 | 1.00 | 25.82 | B | C |
| ATOM | 2061 | CG2 | VAL | B | 362 | 30.414 | 73.417 | 41.594 | 1.00 | 24.04 | B | C |
| ATOM | 2062 | C | VAL | B | 362 | 27.604 | 72.237 | 41.460 | 1.00 | 26.03 | B | C |
| ATOM | 2063 | O | VAL | B | 362 | 27.452 | 71.530 | 42.447 | 1.00 | 27.18 | B | O |
| ATOM | 2064 | N | HIS | B | 363 | 26.825 | 73.280 | 41.214 | 1.00 | 26.28 | B | N |
| ATOM | 2065 | CA | HIS | B | 363 | 25.756 | 73.628 | 42.129 | 1.00 | 27.35 | B | C |
| ATOM | 2066 | CB | HIS | B | 363 | 25.469 | 75.121 | 42.066 | 1.00 | 25.50 | B | C |
| ATOM | 2067 | CG | HIS | B | 363 | 25.134 | 75.716 | 43.395 | 1.00 | 28.66 | B | C |
| ATOM | 2068 | CD2 | HIS | B | 363 | 25.931 | 76.187 | 44.384 | 1.00 | 28.33 | B | C |
| ATOM | 2069 | ND1 | HIS | B | 363 | 23.834 | 75.867 | 43.837 | 1.00 | 25.82 | B | N |
| ATOM | 2070 | CE1 | HIS | B | 363 | 23.848 | 76.408 | 45.042 | 1.00 | 30.03 | B | C |
| ATOM | 2071 | NE2 | HIS | B | 363 | 25.107 | 76.612 | 45.397 | 1.00 | 30.90 | B | N |
| ATOM | 2072 | C | HIS | B | 363 | 24.488 | 72.854 | 41.811 | 1.00 | 30.13 | B | C |
| ATOM | 2073 | O | HIS | B | 363 | 24.121 | 72.697 | 40.649 | 1.00 | 30.15 | B | O |
| ATOM | 2074 | N | ALA | B | 364 | 23.824 | 72.364 | 42.852 | 1.00 | 31.25 | B | N |
| ATOM | 2075 | CA | ALA | B | 364 | 22.585 | 71.617 | 42.683 | 1.00 | 34.87 | B | C |
| ATOM | 2076 | CB | ALA | B | 364 | 22.197 | 70.954 | 44.003 | 1.00 | 32.06 | B | C |
| ATOM | 2077 | C | ALA | B | 364 | 21.471 | 72.560 | 42.209 | 1.00 | 37.84 | B | C |
| ATOM | 2078 | O | ALA | B | 364 | 21.560 | 73.781 | 42.376 | 1.00 | 38.38 | B | O |
| ATOM | 2079 | N | GLY | B | 365 | 20.428 | 71.991 | 41.614 | 1.00 | 42.63 | B | N |
| ATOM | 2080 | CA | GLY | B | 365 | 19.325 | 72.800 | 41.122 | 1.00 | 48.16 | B | C |
| ATOM | 2081 | C | GLY | B | 365 | 17.991 | 72.088 | 41.254 | 1.00 | 52.08 | B | C |
| ATOM | 2082 | O | GLY | B | 365 | 17.895 | 71.192 | 42.128 | 1.00 | 55.37 | B | O |
| ATOM | 2083 | OT | GLY | B | 365 | 17.046 | 72.420 | 40.492 | 1.00 | 53.49 | B | O |
| ATOM | 2084 | CB | LYS | D | 378 | 28.139 | 60.555 | 40.385 | 1.00 | 61.73 | D | C |
| ATOM | 2085 | CG | LYS | D | 378 | 29.106 | 59.829 | 39.448 | 1.00 | 62.72 | D | C |
| ATOM | 2086 | CD | LYS | D | 378 | 28.360 | 58.821 | 38.548 | 1.00 | 65.83 | D | C |
| ATOM | 2087 | CE | LYS | D | 378 | 28.604 | 57.360 | 38.976 | 1.00 | 66.72 | D | C |
| ATOM | 2088 | NZ | LYS | D | 378 | 27.828 | 56.365 | 38.162 | 1.00 | 64.46 | D | N |
| ATOM | 2089 | C | LYS | D | 378 | 28.520 | 62.996 | 40.047 | 1.00 | 56.54 | D | C |
| ATOM | 2090 | O | LYS | D | 378 | 28.236 | 62.769 | 38.870 | 1.00 | 57.39 | D | O |
| ATOM | 2091 | N | LYS | D | 378 | 27.958 | 62.133 | 42.291 | 1.00 | 59.09 | D | N |
| ATOM | 2092 | CA | LYS | D | 378 | 28.685 | 61.841 | 41.023 | 1.00 | 58.59 | D | C |
| ATOM | 2093 | N | TYR | D | 379 | 28.682 | 64.228 | 40.535 | 1.00 | 53.74 | D | N |
| ATOM | 2094 | CA | TYR | D | 379 | 28.556 | 65.398 | 39.671 | 1.00 | 49.99 | D | C |
| ATOM | 2095 | CB | TYR | D | 379 | 27.270 | 66.146 | 39.990 | 1.00 | 53.74 | D | C |
| ATOM | 2096 | CG | TYR | D | 379 | 26.122 | 65.432 | 39.317 | 1.00 | 59.57 | D | C |
| ATOM | 2097 | CD1 | TYR | D | 379 | 25.547 | 64.294 | 39.902 | 1.00 | 62.51 | D | C |
| ATOM | 2098 | CE1 | TYR | D | 379 | 24.579 | 63.537 | 39.229 | 1.00 | 63.96 | D | C |
| ATOM | 2099 | CD2 | TYR | D | 379 | 25.694 | 65.806 | 38.036 | 1.00 | 61.78 | D | C |
| ATOM | 2100 | CE2 | TYR | D | 379 | 24.726 | 65.058 | 37.350 | 1.00 | 64.59 | D | C |
| ATOM | 2101 | CZ | TYR | D | 379 | 24.176 | 63.920 | 37.954 | 1.00 | 65.65 | D | C |
| ATOM | 2102 | OH | TYR | D | 379 | 23.238 | 63.159 | 37.286 | 1.00 | 65.93 | D | O |
| ATOM | 2103 | C | TYR | D | 379 | 29.786 | 66.290 | 39.692 | 1.00 | 46.59 | D | C |
| ATOM | 2104 | O | TYR | D | 379 | 29.921 | 67.251 | 40.459 | 1.00 | 44.84 | D | O |
| ATOM | 2105 | N | ASN | D | 380 | 30.669 | 65.914 | 38.776 | 1.00 | 40.97 | D | N |
| ATOM | 2106 | CA | ASN | D | 380 | 31.979 | 66.485 | 38.540 | 1.00 | 35.19 | D | C |
| ATOM | 2107 | CB | ASN | D | 380 | 32.740 | 65.520 | 37.638 | 1.00 | 35.51 | D | C |
| ATOM | 2108 | CG | ASN | D | 380 | 32.310 | 64.089 | 37.852 | 1.00 | 33.96 | D | C |
| ATOM | 2109 | OD1 | ASN | D | 380 | 32.456 | 63.558 | 38.948 | 1.00 | 36.52 | D | O |
| ATOM | 2110 | ND2 | ASN | D | 380 | 31.762 | 63.462 | 36.816 | 1.00 | 32.74 | D | N |
| ATOM | 2111 | C | ASN | D | 380 | 32.093 | 67.885 | 37.973 | 1.00 | 30.37 | D | C |
| ATOM | 2112 | O | ASN | D | 380 | 31.182 | 68.386 | 37.316 | 1.00 | 27.70 | D | O |
| ATOM | 2113 | N | PRO | D | 381 | 33.243 | 68.532 | 38.229 | 1.00 | 27.04 | D | N |
| ATOM | 2114 | CD | PRO | D | 381 | 34.372 | 68.009 | 39.020 | 1.00 | 24.09 | D | C |
| ATOM | 2115 | CA | PRO | D | 381 | 33.508 | 69.885 | 37.747 | 1.00 | 25.83 | D | C |
| ATOM | 2116 | CB | PRO | D | 381 | 34.917 | 70.180 | 38.258 | 1.00 | 23.18 | D | C |
| ATOM | 2117 | CG | PRO | D | 381 | 35.100 | 69.246 | 39.412 | 1.00 | 23.17 | D | C |
| ATOM | 2118 | C | PRO | D | 381 | 33.428 | 69.886 | 36.228 | 1.00 | 25.45 | D | C |
| ATOM | 2119 | O | PRO | D | 381 | 34.024 | 69.038 | 35.571 | 1.00 | 23.52 | D | O |
| ATOM | 2120 | N | VAL | D | 382 | 32.673 | 70.834 | 35.686 | 1.00 | 26.52 | D | N |
| ATOM | 2121 | CA | VAL | D | 382 | 32.480 | 70.961 | 34.247 | 1.00 | 28.28 | D | C |
| ATOM | 2122 | CB | VAL | D | 382 | 33.733 | 71.590 | 33.583 | 1.00 | 27.18 | D | C |
| ATOM | 2123 | CG1 | VAL | D | 382 | 34.676 | 70.522 | 33.121 | 1.00 | 33.11 | D | C |
| ATOM | 2124 | CG2 | VAL | D | 382 | 33.318 | 72.465 | 32.422 | 1.00 | 28.52 | D | C |
| ATOM | 2125 | C | VAL | D | 382 | 32.121 | 69.617 | 33.592 | 1.00 | 27.65 | D | C |
| ATOM | 2126 | O | VAL | D | 382 | 32.429 | 69.370 | 32.431 | 1.00 | 28.83 | D | O |
| ATOM | 2127 | N | GLY | D | 383 | 31.454 | 68.756 | 34.351 | 1.00 | 27.93 | D | N |
| ATOM | 2128 | CA | GLY | D | 383 | 31.042 | 67.460 | 33.833 | 1.00 | 25.23 | D | C |
| ATOM | 2129 | C | GLY | D | 383 | 32.151 | 66.454 | 33.560 | 1.00 | 26.36 | D | C |
| ATOM | 2130 | O | GLY | D | 383 | 31.901 | 65.381 | 33.004 | 1.00 | 25.48 | D | O |
| ATOM | 2131 | N | ALA | D | 384 | 33.377 | 66.778 | 33.962 | 1.00 | 25.61 | D | N |
| ATOM | 2132 | CA | ALA | D | 384 | 34.516 | 65.899 | 33.729 | 1.00 | 23.85 | D | C |
| ATOM | 2133 | CB | ALA | D | 384 | 35.660 | 66.708 | 33.137 | 1.00 | 21.88 | D | C |
| ATOM | 2134 | C | ALA | D | 384 | 35.001 | 65.128 | 34.973 | 1.00 | 23.76 | D | C |
| ATOM | 2135 | O | ALA | D | 384 | 35.520 | 65.704 | 35.929 | 1.00 | 23.45 | D | O |
| ATOM | 2136 | N | SER | D | 385 | 34.844 | 63.811 | 34.941 | 1.00 | 23.50 | D | N |
| ATOM | 2137 | CA | SER | D | 385 | 35.266 | 62.988 | 36.058 | 1.00 | 23.05 | D | C |
| ATOM | 2138 | CB | SER | D | 385 | 34.852 | 61.535 | 35.821 | 1.00 | 23.47 | D | C |
| ATOM | 2139 | OG | SER | D | 385 | 35.600 | 60.961 | 34.768 | 1.00 | 29.10 | D | O |
| ATOM | 2140 | C | SER | D | 385 | 36.776 | 63.095 | 36.270 | 1.00 | 21.53 | D | C |
| ATOM | 2141 | O | SER | D | 385 | 37.263 | 62.901 | 37.377 | 1.00 | 22.04 | D | O |
| ATOM | 2142 | N | GLU | D | 386 | 37.514 | 63.419 | 35.215 | 1.00 | 22.00 | D | N |
| ATOM | 2143 | CA | GLU | D | 386 | 38.968 | 63.565 | 35.310 | 1.00 | 22.75 | D | C |
| ATOM | 2144 | CB | GLU | D | 386 | 39.588 | 63.865 | 33.946 | 1.00 | 20.74 | D | C |
| ATOM | 2145 | CG | GLU | D | 386 | 39.568 | 62.725 | 32.961 | 1.00 | 26.33 | D | C |
| ATOM | 2146 | CD | GLU | D | 386 | 38.312 | 62.716 | 32.117 | 1.00 | 31.31 | D | C |
| ATOM | 2147 | OE1 | GLU | D | 386 | 38.227 | 61.875 | 31.189 | 1.00 | 33.42 | D | O |
| ATOM | 2148 | OE2 | GLU | D | 386 | 37.413 | 63.550 | 32.384 | 1.00 | 30.73 | D | O |
| ATOM | 2149 | C | GLU | D | 386 | 39.302 | 64.735 | 36.223 | 1.00 | 24.11 | D | C |
| ATOM | 2150 | O | GLU | D | 386 | 40.311 | 64.720 | 36.925 | 1.00 | 23.52 | D | O |
| ATOM | 2151 | N | LEU | D | 387 | 38.456 | 65.760 | 36.189 | 1.00 | 22.88 | D | N |
| ATOM | 2152 | CA | LEU | D | 387 | 38.679 | 66.940 | 37.006 | 1.00 | 23.90 | D | C |
| ATOM | 2153 | CB | LEU | D | 387 | 37.892 | 68.112 | 36.423 | 1.00 | 22.03 | D | C |
| ATOM | 2154 | CG | LEU | D | 387 | 38.396 | 68.523 | 35.034 | 1.00 | 22.46 | D | C |
| ATOM | 2155 | CD1 | LEU | D | 387 | 37.566 | 69.675 | 34.501 | 1.00 | 19.24 | D | C |
| ATOM | 2156 | CD2 | LEU | D | 387 | 39.851 | 68.914 | 35.107 | 1.00 | 18.93 | D | C |
| ATOM | 2157 | C | LEU | D | 387 | 38.311 | 66.692 | 38.475 | 1.00 | 23.25 | D | C |
| ATOM | 2158 | O | LEU | D | 387 | 38.899 | 67.277 | 39.378 | 1.00 | 22.08 | D | O |
| ATOM | 2159 | N | ARG | D | 388 | 37.336 | 65.823 | 38.708 | 1.00 | 23.97 | D | N |
| ATOM | 2160 | CA | ARG | D | 388 | 36.953 | 65.480 | 40.065 | 1.00 | 24.85 | D | C |
| ATOM | 2161 | CB | ARG | D | 388 | 35.665 | 64.636 | 40.035 | 1.00 | 27.33 | D | C |
| ATOM | 2162 | CG | ARG | D | 388 | 35.652 | 63.410 | 40.932 | 1.00 | 32.69 | D | C |
| ATOM | 2163 | CD | ARG | D | 388 | 34.571 | 63.517 | 41.987 | 1.00 | 37.49 | D | C |
| ATOM | 2164 | NE | ARG | D | 388 | 33.497 | 64.436 | 41.598 | 1.00 | 44.43 | D | N |
| ATOM | 2165 | CZ | ARG | D | 388 | 32.750 | 65.134 | 42.456 | 1.00 | 44.94 | D | C |
| ATOM | 2166 | NH1 | ARG | D | 388 | 31.795 | 65.942 | 41.996 | 1.00 | 42.40 | D | N |
| ATOM | 2167 | NH2 | ARG | D | 388 | 32.957 | 65.027 | 43.773 | 1.00 | 44.99 | D | N |
| ATOM | 2168 | C | ARG | D | 388 | 38.136 | 64.688 | 40.655 | 1.00 | 24.23 | D | C |
| ATOM | 2169 | O | ARG | D | 388 | 38.597 | 64.955 | 41.768 | 1.00 | 20.64 | D | O |
| ATOM | 2170 | N | ASP | D | 389 | 38.643 | 63.733 | 39.878 | 1.00 | 21.97 | D | N |
| ATOM | 2171 | CA | ASP | D | 389 | 39.760 | 62.903 | 40.302 | 1.00 | 19.80 | D | C |
| ATOM | 2172 | CB | ASP | D | 389 | 40.119 | 61.915 | 39.201 | 1.00 | 19.65 | D | C |
| ATOM | 2173 | CG | ASP | D | 389 | 39.091 | 60.823 | 39.049 | 1.00 | 26.40 | D | C |
| ATOM | 2174 | OD1 | ASP | D | 389 | 39.157 | 60.098 | 38.036 | 1.00 | 33.56 | D | O |
| ATOM | 2175 | OD2 | ASP | D | 389 | 38.217 | 60.683 | 39.932 | 1.00 | 30.92 | D | O |
| ATOM | 2176 | C | ASP | D | 389 | 40.996 | 63.718 | 40.638 | 1.00 | 19.68 | D | C |
| ATOM | 2177 | O | ASP | D | 389 | 41.736 | 63.391 | 41.568 | 1.00 | 18.31 | D | O |
| ATOM | 2178 | N | LEU | D | 390 | 41.223 | 64.779 | 39.871 | 1.00 | 18.23 | D | N |
| ATOM | 2179 | CA | LEU | D | 390 | 42.405 | 65.624 | 40.060 | 1.00 | 17.56 | D | C |
| ATOM | 2180 | CB | LEU | D | 390 | 42.701 | 66.372 | 38.758 | 1.00 | 15.03 | D | C |
| ATOM | 2181 | CG | LEU | D | 390 | 43.838 | 67.389 | 38.754 | 1.00 | 18.05 | D | C |
| ATOM | 2182 | CD1 | LEU | D | 390 | 45.164 | 66.691 | 39.040 | 1.00 | 18.65 | D | C |
| ATOM | 2183 | CD2 | LEU | D | 390 | 43.902 | 68.072 | 37.403 | 1.00 | 14.47 | D | C |
| ATOM | 2184 | C | LEU | D | 390 | 42.326 | 66.631 | 41.210 | 1.00 | 16.15 | D | C |
| ATOM | 2185 | O | LEU | D | 390 | 43.278 | 66.796 | 41.973 | 1.00 | 14.30 | D | O |
| ATOM | 2186 | N | TYR | D | 391 | 41.185 | 67.294 | 41.329 | 1.00 | 14.40 | D | N |
| ATOM | 2187 | CA | TYR | D | 391 | 40.986 | 68.312 | 42.353 | 1.00 | 16.31 | D | C |
| ATOM | 2188 | CB | TYR | D | 391 | 40.196 | 69.479 | 41.738 | 1.00 | 14.06 | D | C |
| ATOM | 2189 | CG | TYR | D | 391 | 40.966 | 70.224 | 40.679 | 1.00 | 13.94 | D | C |
| ATOM | 2190 | CD1 | TYR | D | 391 | 41.951 | 71.148 | 41.030 | 1.00 | 12.12 | D | C |
| ATOM | 2191 | CE1 | TYR | D | 391 | 42.702 | 71.808 | 40.063 | 1.00 | 14.33 | D | C |
| ATOM | 2192 | CD2 | TYR | D | 391 | 40.738 | 69.975 | 39.325 | 1.00 | 13.49 | D | C |
| ATOM | 2193 | CE2 | TYR | D | 391 | 41.479 | 70.628 | 38.336 | 1.00 | 17.15 | D | C |
| ATOM | 2194 | CZ | TYR | D | 391 | 42.463 | 71.542 | 38.712 | 1.00 | 17.87 | D | C |
| ATOM | 2195 | OH | TYR | D | 391 | 43.215 | 72.181 | 37.753 | 1.00 | 16.08 | D | O |
| ATOM | 2196 | C | TYR | D | 391 | 40.288 | 67.890 | 43.658 | 1.00 | 16.29 | D | C |
| ATOM | 2197 | O | TYR | D | 391 | 40.486 | 68.528 | 44.693 | 1.00 | 17.42 | D | O |
| ATOM | 2198 | N | LEU | D | 392 | 39.487 | 66.829 | 43.611 | 1.00 | 14.74 | D | N |
| ATOM | 2199 | CA | LEU | D | 392 | 38.701 | 66.427 | 44.768 | 1.00 | 17.11 | D | C |
| ATOM | 2200 | CB | LEU | D | 392 | 37.210 | 66.615 | 44.448 | 1.00 | 17.47 | D | C |
| ATOM | 2201 | CG | LEU | D | 392 | 36.813 | 67.978 | 43.843 | 1.00 | 19.53 | D | C |
| ATOM | 2202 | CD1 | LEU | D | 392 | 35.367 | 67.944 | 43.328 | 1.00 | 15.21 | D | C |
| ATOM | 2203 | CD2 | LEU | D | 392 | 36.987 | 69.076 | 44.904 | 1.00 | 18.99 | D | C |
| ATOM | 2204 | C | LEU | D | 392 | 38.919 | 65.034 | 45.332 | 1.00 | 18.26 | D | C |
| ATOM | 2205 | O | LEU | D | 392 | 38.030 | 64.492 | 46.001 | 1.00 | 18.05 | D | O |
| ATOM | 2206 | N | LYS | D | 393 | 40.094 | 64.460 | 45.079 | 1.00 | 18.33 | D | N |
| ATOM | 2207 | CA | LYS | D | 393 | 40.411 | 63.140 | 45.594 | 1.00 | 17.85 | D | C |
| ATOM | 2208 | CB | LYS | D | 393 | 40.457 | 62.129 | 44.465 | 1.00 | 20.57 | D | C |
| ATOM | 2209 | CG | LYS | D | 393 | 39.153 | 61.977 | 43.748 | 1.00 | 23.56 | D | C |
| ATOM | 2210 | CD | LYS | D | 393 | 38.779 | 60.521 | 43.671 | 1.00 | 28.09 | D | C |
| ATOM | 2211 | CE | LYS | D | 393 | 37.290 | 60.377 | 43.455 | 1.00 | 32.85 | D | C |
| ATOM | 2212 | NZ | LYS | D | 393 | 37.055 | 59.372 | 42.388 | 1.00 | 40.25 | D | N |
| ATOM | 2213 | C | LYS | D | 393 | 41.755 | 63.165 | 46.290 | 1.00 | 17.90 | D | C |
| ATOM | 2214 | O | LYS | D | 393 | 42.605 | 64.001 | 45.986 | 1.00 | 14.31 | D | O |
| ATOM | 2215 | N | THR | D | 394 | 41.945 | 62.238 | 47.225 | 1.00 | 18.58 | D | N |
| ATOM | 2216 | CA | THR | D | 394 | 43.201 | 62.142 | 47.964 | 1.00 | 18.53 | D | C |
| ATOM | 2217 | CB | THR | D | 394 | 42.966 | 61.594 | 49.405 | 1.00 | 14.71 | D | C |
| ATOM | 2218 | OG1 | THR | D | 394 | 42.390 | 60.286 | 49.342 | 1.00 | 17.47 | D | O |
| ATOM | 2219 | CG2 | THR | D | 394 | 42.026 | 62.495 | 50.168 | 1.00 | 14.68 | D | C |
| ATOM | 2220 | C | THR | D | 394 | 44.197 | 61.235 | 47.225 | 1.00 | 19.85 | D | C |
| ATOM | 2221 | O | THR | D | 394 | 45.409 | 61.379 | 47.360 | 1.00 | 21.28 | D | O |
| ATOM | 2222 | N | ASP | D | 395 | 43.686 | 60.303 | 46.436 | 1.00 | 22.21 | D | N |
| ATOM | 2223 | CA | ASP | D | 395 | 44.559 | 59.404 | 45.693 | 1.00 | 24.78 | D | C |
| ATOM | 2224 | CB | ASP | D | 395 | 44.202 | 57.940 | 46.000 | 1.00 | 28.20 | D | C |
| ATOM | 2225 | CG | ASP | D | 395 | 45.272 | 56.954 | 45.517 | 1.00 | 36.52 | D | C |
| ATOM | 2226 | OD1 | ASP | D | 395 | 46.453 | 57.361 | 45.376 | 1.00 | 40.38 | D | O |
| ATOM | 2227 | OD2 | ASP | D | 395 | 44.937 | 55.766 | 45.275 | 1.00 | 40.52 | D | O |
| ATOM | 2228 | C | ASP | D | 395 | 44.478 | 59.644 | 44.179 | 1.00 | 23.48 | D | C |
| ATOM | 2229 | O | ASP | D | 395 | 43.436 | 59.474 | 43.561 | 1.00 | 21.85 | D | O |
| ATOM | 2230 | N | ASN | D | 396 | 45.589 | 60.062 | 43.592 | 1.00 | 23.47 | D | N |
| ATOM | 2231 | CA | ASN | D | 396 | 45.643 | 60.277 | 42.158 | 1.00 | 21.59 | D | C |
| ATOM | 2232 | CB | ASN | D | 396 | 44.786 | 61.486 | 41.734 | 1.00 | 19.87 | D | C |
| ATOM | 2233 | CG | ASN | D | 396 | 45.259 | 62.796 | 42.342 | 1.00 | 19.47 | D | C |
| ATOM | 2234 | OD1 | ASN | D | 396 | 44.487 | 63.756 | 42.455 | 1.00 | 19.51 | D | O |
| ATOM | 2235 | ND2 | ASN | D | 396 | 46.522 | 62.848 | 42.731 | 1.00 | 13.60 | D | N |
| ATOM | 2236 | C | ASN | D | 396 | 47.087 | 60.442 | 41.738 | 1.00 | 20.10 | D | C |
| ATOM | 2237 | O | ASN | D | 396 | 47.992 | 60.220 | 42.531 | 1.00 | 20.30 | D | O |
| ATOM | 2238 | N | TYR | D | 397 | 47.300 | 60.840 | 40.493 | 1.00 | 20.03 | D | N |
| ATOM | 2239 | CA | TYR | D | 397 | 48.643 | 60.991 | 39.968 | 1.00 | 20.19 | D | C |
| ATOM | 2240 | CB | TYR | D | 397 | 48.590 | 61.419 | 38.498 | 1.00 | 21.06 | D | C |
| ATOM | 2241 | CG | TYR | D | 397 | 49.926 | 61.287 | 37.802 | 1.00 | 23.50 | D | C |
| ATOM | 2242 | CD1 | TYR | D | 397 | 50.816 | 62.360 | 37.758 | 1.00 | 23.02 | D | C |
| ATOM | 2243 | CE1 | TYR | D | 397 | 52.071 | 62.231 | 37.176 | 1.00 | 25.06 | D | C |
| ATOM | 2244 | CD2 | TYR | D | 397 | 50.325 | 60.072 | 37.237 | 1.00 | 24.58 | D | C |
| ATOM | 2245 | CE2 | TYR | D | 397 | 51.583 | 59.926 | 36.650 | 1.00 | 24.46 | D | C |
| ATOM | 2246 | CZ | TYR | D | 397 | 52.452 | 61.004 | 36.621 | 1.00 | 29.08 | D | C |
| ATOM | 2247 | OH | TYR | D | 397 | 53.698 | 60.851 | 36.037 | 1.00 | 31.29 | D | O |
| ATOM | 2248 | C | TYR | D | 397 | 49.532 | 61.947 | 40.753 | 1.00 | 22.39 | D | C |
| ATOM | 2249 | O | TYR | D | 397 | 50.760 | 61.760 | 40.833 | 1.00 | 21.63 | D | O |
| ATOM | 2250 | N | ILE | D | 398 | 48.940 | 62.982 | 41.328 | 1.00 | 21.07 | D | N |
| ATOM | 2251 | CA | ILE | D | 398 | 49.748 | 63.915 | 42.091 | 1.00 | 20.57 | D | C |
| ATOM | 2252 | CB | ILE | D | 398 | 49.459 | 65.388 | 41.691 | 1.00 | 20.16 | D | C |
| ATOM | 2253 | CG2 | ILE | D | 398 | 50.045 | 65.659 | 40.318 | 1.00 | 19.83 | D | C |
| ATOM | 2254 | CG1 | ILE | D | 398 | 47.956 | 65.671 | 41.691 | 1.00 | 17.45 | D | C |
| ATOM | 2255 | CD1 | ILE | D | 398 | 47.626 | 67.140 | 41.726 | 1.00 | 15.45 | D | C |
| ATOM | 2256 | C | ILE | D | 398 | 49.508 | 63.703 | 43.574 | 1.00 | 21.12 | D | C |
| ATOM | 2257 | O | ILE | D | 398 | 49.662 | 64.619 | 44.369 | 1.00 | 24.13 | D | O |
| ATOM | 2258 | N | ASN | D | 399 | 49.134 | 62.477 | 43.934 | 1.00 | 22.94 | D | N |
| ATOM | 2259 | CA | ASN | D | 399 | 48.872 | 62.098 | 45.325 | 1.00 | 24.00 | D | C |
| ATOM | 2260 | CB | ASN | D | 399 | 50.194 | 61.900 | 46.059 | 1.00 | 27.73 | D | C |
| ATOM | 2261 | CG | ASN | D | 399 | 51.099 | 60.918 | 45.348 | 1.00 | 30.92 | D | C |
| ATOM | 2262 | OD1 | ASN | D | 399 | 50.701 | 59.783 | 45.070 | 1.00 | 35.81 | D | O |
| ATOM | 2263 | ND2 | ASN | D | 399 | 52.319 | 61.350 | 45.034 | 1.00 | 29.80 | D | N |
| ATOM | 2264 | C | ASN | D | 399 | 47.992 | 63.067 | 46.105 | 1.00 | 23.18 | D | C |
| ATOM | 2265 | O | ASN | D | 399 | 48.351 | 63.497 | 47.202 | 1.00 | 22.90 | D | O |
| ATOM | 2266 | N | GLY | D | 400 | 46.849 | 63.403 | 45.515 | 1.00 | 20.12 | D | N |
| ATOM | 2267 | CA | GLY | D | 400 | 45.884 | 64.287 | 46.140 | 1.00 | 19.69 | D | C |
| ATOM | 2268 | C | GLY | D | 400 | 46.379 | 65.639 | 46.590 | 1.00 | 16.64 | D | C |
| ATOM | 2269 | O | GLY | D | 400 | 45.781 | 66.272 | 47.444 | 1.00 | 17.56 | D | O |
| ATOM | 2270 | N | GLU | D | 401 | 47.458 | 66.113 | 46.007 | 1.00 | 16.96 | D | N |
| ATOM | 2271 | CA | GLU | D | 401 | 47.972 | 67.397 | 46.432 | 1.00 | 18.86 | D | C |
| ATOM | 2272 | CB | GLU | D | 401 | 49.277 | 67.714 | 45.707 | 1.00 | 19.79 | D | C |
| ATOM | 2273 | CG | GLU | D | 401 | 49.735 | 69.133 | 45.949 | 1.00 | 24.48 | D | C |
| ATOM | 2274 | CD | GLU | D | 401 | 50.886 | 69.539 | 45.055 | 1.00 | 29.62 | D | C |
| ATOM | 2275 | OE1 | GLU | D | 401 | 51.832 | 68.718 | 44.906 | 1.00 | 29.83 | D | O |
| ATOM | 2276 | OE2 | GLU | D | 401 | 50.833 | 70.676 | 44.511 | 1.00 | 24.20 | D | O |
| ATOM | 2277 | C | GLU | D | 401 | 47.023 | 68.580 | 46.283 | 1.00 | 19.29 | D | C |
| ATOM | 2278 | O | GLU | D | 401 | 46.992 | 69.450 | 47.158 | 1.00 | 21.91 | D | O |
| ATOM | 2279 | N | TYR | D | 402 | 46.269 | 68.637 | 45.190 | 1.00 | 15.40 | D | N |
| ATOM | 2280 | CA | TYR | D | 402 | 45.352 | 69.755 | 44.964 | 1.00 | 16.61 | D | C |
| ATOM | 2281 | CB | TYR | D | 402 | 44.745 | 69.681 | 43.550 | 1.00 | 17.42 | D | C |
| ATOM | 2282 | CG | TYR | D | 402 | 45.684 | 70.135 | 42.446 | 1.00 | 19.44 | D | C |
| ATOM | 2283 | CD1 | TYR | D | 402 | 46.955 | 70.625 | 42.746 | 1.00 | 21.17 | D | C |
| ATOM | 2284 | CE1 | TYR | D | 402 | 47.818 | 71.053 | 41.750 | 1.00 | 20.51 | D | C |
| ATOM | 2285 | CD2 | TYR | D | 402 | 45.303 | 70.079 | 41.109 | 1.00 | 17.41 | D | C |
| ATOM | 2286 | CE2 | TYR | D | 402 | 46.159 | 70.503 | 40.101 | 1.00 | 17.33 | D | C |
| ATOM | 2287 | CZ | TYR | D | 402 | 47.415 | 70.995 | 40.427 | 1.00 | 21.86 | D | C |
| ATOM | 2288 | OH | TYR | D | 402 | 48.263 | 71.485 | 39.453 | 1.00 | 16.83 | D | O |
| ATOM | 2289 | C | TYR | D | 402 | 44.229 | 69.786 | 45.998 | 1.00 | 16.61 | D | C |
| ATOM | 2290 | O | TYR | D | 402 | 43.886 | 70.844 | 46.520 | 1.00 | 14.31 | D | O |
| ATOM | 2291 | N | PHE | D | 403 | 43.657 | 68.614 | 46.270 | 1.00 | 17.92 | D | N |
| ATOM | 2292 | CA | PHE | D | 403 | 42.576 | 68.463 | 47.235 | 1.00 | 16.79 | D | C |
| ATOM | 2293 | CB | PHE | D | 403 | 42.143 | 66.991 | 47.292 | 1.00 | 17.82 | D | C |
| ATOM | 2294 | CG | PHE | D | 403 | 40.918 | 66.749 | 48.121 | 1.00 | 17.21 | D | C |
| ATOM | 2295 | CD1 | PHE | D | 403 | 39.903 | 67.701 | 48.184 | 1.00 | 17.57 | D | C |
| ATOM | 2296 | CD2 | PHE | D | 403 | 40.765 | 65.551 | 48.816 | 1.00 | 17.82 | D | C |
| ATOM | 2297 | CE1 | PHE | D | 403 | 38.742 | 67.465 | 48.930 | 1.00 | 17.70 | D | C |
| ATOM | 2298 | CE2 | PHE | D | 403 | 39.609 | 65.301 | 49.564 | 1.00 | 18.05 | D | C |
| ATOM | 2299 | CZ | PHE | D | 403 | 38.594 | 66.267 | 49.618 | 1.00 | 16.96 | D | C |
| ATOM | 2300 | C | PHE | D | 403 | 43.085 | 68.925 | 48.603 | 1.00 | 17.90 | D | C |
| ATOM | 2301 | O | PHE | D | 403 | 42.383 | 69.629 | 49.337 | 1.00 | 18.59 | D | O |
| ATOM | 2302 | N | ALA | D | 404 | 44.314 | 68.529 | 48.934 | 1.00 | 16.04 | D | N |
| ATOM | 2303 | CA | ALA | D | 404 | 44.925 | 68.910 | 50.204 | 1.00 | 16.03 | D | C |
| ATOM | 2304 | CB | ALA | D | 404 | 46.296 | 68.296 | 50.320 | 1.00 | 11.20 | D | C |
| ATOM | 2305 | C | ALA | D | 404 | 45.027 | 70.427 | 50.287 | 1.00 | 17.49 | D | C |
| ATOM | 2306 | O | ALA | D | 404 | 44.639 | 71.042 | 51.285 | 1.00 | 17.76 | D | O |
| ATOM | 2307 | N | THR | D | 405 | 45.542 | 71.033 | 49.223 | 1.00 | 16.94 | D | N |
| ATOM | 2308 | CA | THR | D | 405 | 45.695 | 72.474 | 49.180 | 1.00 | 15.76 | D | C |
| ATOM | 2309 | CB | THR | D | 405 | 46.437 | 72.901 | 47.902 | 1.00 | 15.75 | D | C |
| ATOM | 2310 | OG1 | THR | D | 405 | 47.691 | 72.216 | 47.847 | 1.00 | 14.60 | D | O |
| ATOM | 2311 | CG2 | THR | D | 405 | 46.691 | 74.401 | 47.896 | 1.00 | 10.69 | D | C |
| ATOM | 2312 | C | THR | D | 405 | 44.370 | 73.222 | 49.283 | 1.00 | 15.81 | D | C |
| ATOM | 2313 | O | THR | D | 405 | 44.296 | 74.239 | 49.972 | 1.00 | 19.43 | D | O |
| ATOM | 2314 | N | ILE | D | 406 | 43.329 | 72.739 | 48.611 | 1.00 | 16.01 | D | N |
| ATOM | 2315 | CA | ILE | D | 406 | 42.032 | 73.411 | 48.684 | 1.00 | 17.99 | D | C |
| ATOM | 2316 | CB | ILE | D | 406 | 40.972 | 72.761 | 47.746 | 1.00 | 20.69 | D | C |
| ATOM | 2317 | CG2 | ILE | D | 406 | 39.635 | 73.477 | 47.906 | 1.00 | 19.77 | D | C |
| ATOM | 2318 | CG1 | ILE | D | 406 | 41.411 | 72.873 | 46.278 | 1.00 | 23.62 | D | C |
| ATOM | 2319 | CD1 | ILE | D | 406 | 40.549 | 72.063 | 45.294 | 1.00 | 22.99 | D | C |
| ATOM | 2320 | C | ILE | D | 406 | 41.512 | 73.321 | 50.127 | 1.00 | 18.49 | D | C |
| ATOM | 2321 | O | ILE | D | 406 | 41.021 | 74.303 | 50.688 | 1.00 | 17.42 | D | O |
| ATOM | 2322 | N | ILE | D | 407 | 41.632 | 72.136 | 50.716 | 1.00 | 15.98 | D | N |
| ATOM | 2323 | CA | ILE | D | 407 | 41.178 | 71.899 | 52.077 | 1.00 | 17.62 | D | C |
| ATOM | 2324 | CB | ILE | D | 407 | 41.394 | 70.429 | 52.466 | 1.00 | 16.80 | D | C |
| ATOM | 2325 | CG2 | ILE | D | 407 | 41.604 | 70.287 | 53.956 | 1.00 | 16.72 | D | C |
| ATOM | 2326 | CG1 | ILE | D | 407 | 40.182 | 69.615 | 52.046 | 1.00 | 16.87 | D | C |
| ATOM | 2327 | CD1 | ILE | D | 407 | 40.493 | 68.154 | 51.937 | 1.00 | 21.72 | D | C |
| ATOM | 2328 | C | ILE | D | 407 | 41.868 | 72.801 | 53.100 | 1.00 | 18.55 | D | C |
| ATOM | 2329 | O | ILE | D | 407 | 41.218 | 73.336 | 53.995 | 1.00 | 19.24 | D | O |
| ATOM | 2330 | N | LYS | D | 408 | 43.176 | 72.978 | 52.976 | 1.00 | 19.01 | D | N |
| ATOM | 2331 | CA | LYS | D | 408 | 43.880 | 73.829 | 53.920 | 1.00 | 18.57 | D | C |
| ATOM | 2332 | CB | LYS | D | 408 | 45.382 | 73.679 | 53.737 | 1.00 | 20.54 | D | C |
| ATOM | 2333 | CG | LYS | D | 408 | 45.930 | 72.452 | 54.455 | 1.00 | 22.21 | D | C |
| ATOM | 2334 | CD | LYS | D | 408 | 46.809 | 71.621 | 53.559 | 1.00 | 27.39 | D | C |
| ATOM | 2335 | CE | LYS | D | 408 | 48.195 | 72.246 | 53.442 | 1.00 | 27.83 | D | C |
| ATOM | 2336 | NZ | LYS | D | 408 | 48.688 | 72.677 | 54.787 | 1.00 | 28.60 | D | N |
| ATOM | 2337 | C | LYS | D | 408 | 43.457 | 75.282 | 53.756 | 1.00 | 19.95 | D | C |
| ATOM | 2338 | O | LYS | D | 408 | 43.506 | 76.074 | 54.710 | 1.00 | 20.00 | D | O |
| ATOM | 2339 | N | GLU | D | 409 | 43.035 | 75.634 | 52.549 | 1.00 | 15.25 | D | N |
| ATOM | 2340 | CA | GLU | D | 409 | 42.581 | 76.984 | 52.305 | 1.00 | 15.64 | D | C |
| ATOM | 2341 | CB | GLU | D | 409 | 42.441 | 77.233 | 50.802 | 1.00 | 17.04 | D | C |
| ATOM | 2342 | CG | GLU | D | 409 | 43.782 | 77.242 | 50.076 | 1.00 | 18.02 | D | C |
| ATOM | 2343 | CD | GLU | D | 409 | 43.667 | 77.629 | 48.610 | 1.00 | 20.33 | D | C |
| ATOM | 2344 | OE1 | GLU | D | 409 | 42.566 | 77.492 | 48.033 | 1.00 | 20.00 | D | O |
| ATOM | 2345 | OE2 | GLU | D | 409 | 44.688 | 78.067 | 48.028 | 1.00 | 22.08 | D | O |
| ATOM | 2346 | C | GLU | D | 409 | 41.241 | 77.175 | 53.016 | 1.00 | 15.49 | D | C |
| ATOM | 2347 | O | GLU | D | 409 | 40.965 | 78.238 | 53.552 | 1.00 | 17.32 | D | O |
| ATOM | 2348 | N | VAL | D | 410 | 40.407 | 76.146 | 53.016 | 1.00 | 16.70 | D | N |
| ATOM | 2349 | CA | VAL | D | 410 | 39.118 | 76.215 | 53.695 | 1.00 | 15.60 | D | C |
| ATOM | 2350 | CB | VAL | D | 410 | 38.290 | 74.940 | 53.439 | 1.00 | 16.84 | D | C |
| ATOM | 2351 | CG1 | VAL | D | 410 | 36.997 | 74.983 | 54.258 | 1.00 | 13.85 | D | C |
| ATOM | 2352 | CG2 | VAL | D | 410 | 37.987 | 74.797 | 51.930 | 1.00 | 11.42 | D | C |
| ATOM | 2353 | C | VAL | D | 410 | 39.392 | 76.345 | 55.205 | 1.00 | 20.90 | D | C |
| ATOM | 2354 | O | VAL | D | 410 | 38.782 | 77.170 | 55.893 | 1.00 | 21.51 | D | O |
| ATOM | 2355 | N | GLY | D | 411 | 40.334 | 75.547 | 55.705 | 1.00 | 19.07 | D | N |
| ATOM | 2356 | CA | GLY | D | 411 | 40.671 | 75.594 | 57.111 | 1.00 | 18.00 | D | C |
| ATOM | 2357 | C | GLY | D | 411 | 41.135 | 76.966 | 57.543 | 1.00 | 21.64 | D | C |
| ATOM | 2358 | O | GLY | D | 411 | 40.748 | 77.449 | 58.614 | 1.00 | 21.28 | D | O |
| ATOM | 2359 | N | ALA | D | 412 | 41.967 | 77.606 | 56.723 | 1.00 | 20.18 | D | N |
| ATOM | 2360 | CA | ALA | D | 412 | 42.469 | 78.933 | 57.063 | 1.00 | 20.14 | D | C |
| ATOM | 2361 | CB | ALA | D | 412 | 43.580 | 79.335 | 56.109 | 1.00 | 18.72 | D | C |
| ATOM | 2362 | C | ALA | D | 412 | 41.366 | 79.993 | 57.062 | 1.00 | 20.96 | D | C |
| ATOM | 2363 | O | ALA | D | 412 | 41.462 | 81.004 | 57.763 | 1.00 | 20.52 | D | O |
| ATOM | 2364 | N | ASP | D | 413 | 40.324 | 79.772 | 56.270 | 1.00 | 20.31 | D | N |
| ATOM | 2365 | CA | ASP | D | 413 | 39.214 | 80.715 | 56.222 | 1.00 | 21.06 | D | C |
| ATOM | 2366 | CB | ASP | D | 413 | 38.278 | 80.377 | 55.064 | 1.00 | 25.50 | D | C |
| ATOM | 2367 | CG | ASP | D | 413 | 38.774 | 80.927 | 53.720 | 1.00 | 29.94 | D | C |
| ATOM | 2368 | OD1 | ASP | D | 413 | 38.282 | 80.444 | 52.668 | 1.00 | 32.26 | D | O |
| ATOM | 2369 | OD2 | ASP | D | 413 | 39.646 | 81.833 | 53.716 | 1.00 | 27.79 | D | O |
| ATOM | 2370 | C | ASP | D | 413 | 38.460 | 80.575 | 57.538 | 1.00 | 21.82 | D | C |
| ATOM | 2371 | O | ASP | D | 413 | 37.980 | 81.552 | 58.106 | 1.00 | 21.76 | D | O |
| ATOM | 2372 | N | LEU | D | 414 | 38.358 | 79.333 | 58.002 | 1.00 | 20.07 | D | N |
| ATOM | 2373 | CA | LEU | D | 414 | 37.696 | 78.998 | 59.254 | 1.00 | 19.90 | D | C |
| ATOM | 2374 | CB | LEU | D | 414 | 37.703 | 77.482 | 59.427 | 1.00 | 16.71 | D | C |
| ATOM | 2375 | CG | LEU | D | 414 | 36.408 | 76.693 | 59.262 | 1.00 | 20.37 | D | C |
| ATOM | 2376 | CD1 | LEU | D | 414 | 35.410 | 77.449 | 58.427 | 1.00 | 16.20 | D | C |
| ATOM | 2377 | CD2 | LEU | D | 414 | 36.725 | 75.360 | 58.657 | 1.00 | 17.07 | D | C |
| ATOM | 2378 | C | LEU | D | 414 | 38.450 | 79.667 | 60.418 | 1.00 | 20.16 | D | C |
| ATOM | 2379 | O | LEU | D | 414 | 37.846 | 80.331 | 61.268 | 1.00 | 20.36 | D | O |
| ATOM | 2380 | N | VAL | D | 415 | 39.770 | 79.491 | 60.437 | 1.00 | 18.79 | D | N |
| ATOM | 2381 | CA | VAL | D | 415 | 40.606 | 80.074 | 61.473 | 1.00 | 19.80 | D | C |
| ATOM | 2382 | CB | VAL | D | 415 | 42.087 | 79.712 | 61.263 | 1.00 | 18.80 | D | C |
| ATOM | 2383 | CG1 | VAL | D | 415 | 42.971 | 80.552 | 62.175 | 1.00 | 16.17 | D | C |
| ATOM | 2384 | CG2 | VAL | D | 415 | 42.295 | 78.239 | 61.539 | 1.00 | 15.64 | D | C |
| ATOM | 2385 | C | VAL | D | 415 | 40.466 | 81.593 | 61.510 | 1.00 | 22.32 | D | C |
| ATOM | 2386 | O | VAL | D | 415 | 40.528 | 82.197 | 62.574 | 1.00 | 23.15 | D | O |
| ATOM | 2387 | N | ASP | D | 416 | 40.263 | 82.212 | 60.354 | 1.00 | 25.11 | D | N |
| ATOM | 2388 | CA | ASP | D | 416 | 40.118 | 83.663 | 60.304 | 1.00 | 26.79 | D | C |
| ATOM | 2389 | CB | ASP | D | 416 | 40.161 | 84.166 | 58.869 | 1.00 | 32.61 | D | C |
| ATOM | 2390 | CG | ASP | D | 416 | 41.565 | 84.316 | 58.348 | 1.00 | 41.98 | D | C |
| ATOM | 2391 | OD1 | ASP | D | 416 | 41.703 | 84.369 | 57.099 | 1.00 | 47.96 | D | O |
| ATOM | 2392 | OD2 | ASP | D | 416 | 42.519 | 84.381 | 59.172 | 1.00 | 42.34 | D | O |
| ATOM | 2393 | C | ASP | D | 416 | 38.804 | 84.095 | 60.906 | 1.00 | 24.93 | D | C |
| ATOM | 2394 | O | ASP | D | 416 | 38.728 | 85.135 | 61.551 | 1.00 | 24.62 | D | O |
| ATOM | 2395 | N | ALA | D | 417 | 37.762 | 83.305 | 60.675 | 1.00 | 23.37 | D | N |
| ATOM | 2396 | CA | ALA | D | 417 | 36.441 | 83.632 | 61.201 | 1.00 | 20.82 | D | C |
| ATOM | 2397 | CB | ALA | D | 417 | 35.381 | 82.899 | 60.423 | 1.00 | 22.64 | D | C |
| ATOM | 2398 | C | ALA | D | 417 | 36.364 | 83.262 | 62.669 | 1.00 | 18.90 | D | C |
| ATOM | 2399 | O | ALA | D | 417 | 35.452 | 83.692 | 63.366 | 1.00 | 21.11 | D | O |
| ATOM | 2400 | N | LYS | D | 418 | 37.303 | 82.425 | 63.111 | 1.00 | 17.57 | D | N |
| ATOM | 2401 | CA | LYS | D | 418 | 37.433 | 81.995 | 64.510 | 1.00 | 16.99 | D | C |
| ATOM | 2402 | CB | LYS | D | 418 | 37.734 | 83.213 | 65.406 | 1.00 | 18.31 | D | C |
| ATOM | 2403 | CG | LYS | D | 418 | 37.728 | 82.915 | 66.925 | 1.00 | 20.04 | D | C |
| ATOM | 2404 | CD | LYS | D | 418 | 38.160 | 84.133 | 67.726 | 1.00 | 23.39 | D | C |
| ATOM | 2405 | CE | LYS | D | 418 | 38.498 | 83.784 | 69.171 | 1.00 | 25.99 | D | C |
| ATOM | 2406 | NZ | LYS | D | 418 | 38.494 | 85.008 | 70.036 | 1.00 | 28.34 | D | N |
| ATOM | 2407 | C | LYS | D | 418 | 36.340 | 81.186 | 65.209 | 1.00 | 18.65 | D | C |
| ATOM | 2408 | O | LYS | D | 418 | 36.649 | 80.171 | 65.851 | 1.00 | 19.18 | D | O |
| ATOM | 2409 | N | TYR | D | 419 | 35.081 | 81.619 | 65.109 | 1.00 | 15.56 | D | N |
| ATOM | 2410 | CA | TYR | D | 419 | 34.014 | 80.943 | 65.841 | 1.00 | 15.58 | D | C |
| ATOM | 2411 | CB | TYR | D | 419 | 32.973 | 81.979 | 66.260 | 1.00 | 15.29 | D | C |
| ATOM | 2412 | CG | TYR | D | 419 | 33.595 | 83.080 | 67.087 | 1.00 | 18.34 | D | C |
| ATOM | 2413 | CD1 | TYR | D | 419 | 34.028 | 82.836 | 68.393 | 1.00 | 20.41 | D | C |
| ATOM | 2414 | CE1 | TYR | D | 419 | 34.699 | 83.815 | 69.133 | 1.00 | 20.29 | D | C |
| ATOM | 2415 | CD2 | TYR | D | 419 | 33.837 | 84.337 | 66.542 | 1.00 | 17.25 | D | C |
| ATOM | 2416 | CE2 | TYR | D | 419 | 34.507 | 85.328 | 67.271 | 1.00 | 18.61 | D | C |
| ATOM | 2417 | CZ | TYR | D | 419 | 34.939 | 85.056 | 68.564 | 1.00 | 23.50 | D | C |
| ATOM | 2418 | OH | TYR | D | 419 | 35.641 | 86.009 | 69.274 | 1.00 | 27.05 | D | O |
| ATOM | 2419 | C | TYR | D | 419 | 33.341 | 79.725 | 65.231 | 1.00 | 18.06 | D | C |
| ATOM | 2420 | O | TYR | D | 419 | 32.638 | 78.990 | 65.942 | 1.00 | 14.56 | D | O |
| ATOM | 2421 | N | GLN | D | 420 | 33.555 | 79.504 | 63.929 | 1.00 | 17.70 | D | N |
| ATOM | 2422 | CA | GLN | D | 420 | 32.984 | 78.341 | 63.250 | 1.00 | 15.87 | D | C |
| ATOM | 2423 | CB | GLN | D | 420 | 32.418 | 78.734 | 61.878 | 1.00 | 18.42 | D | C |
| ATOM | 2424 | CG | GLN | D | 420 | 31.073 | 79.444 | 61.941 | 1.00 | 18.37 | D | C |
| ATOM | 2425 | CD | GLN | D | 420 | 31.188 | 80.823 | 62.557 | 1.00 | 26.23 | D | C |
| ATOM | 2426 | OE1 | GLN | D | 420 | 30.743 | 81.058 | 63.688 | 1.00 | 28.62 | D | O |
| ATOM | 2427 | NE2 | GLN | D | 420 | 31.795 | 81.747 | 61.819 | 1.00 | 25.87 | D | N |
| ATOM | 2428 | C | GLN | D | 420 | 34.017 | 77.220 | 63.081 | 1.00 | 13.90 | D | C |
| ATOM | 2429 | O | GLN | D | 420 | 35.177 | 77.457 | 62.736 | 1.00 | 14.16 | D | O |
| ATOM | 2430 | N | HIS | D | 421 | 33.564 | 75.995 | 63.328 | 1.00 | 12.53 | D | N |
| ATOM | 2431 | CA | HIS | D | 421 | 34.383 | 74.794 | 63.220 | 1.00 | 11.17 | D | C |
| ATOM | 2432 | CB | HIS | D | 421 | 34.541 | 74.157 | 64.617 | 1.00 | 9.26 | D | C |
| ATOM | 2433 | CG | HIS | D | 421 | 35.304 | 75.010 | 65.584 | 1.00 | 8.51 | D | C |
| ATOM | 2434 | CD2 | HIS | D | 421 | 34.967 | 76.158 | 66.216 | 1.00 | 6.15 | D | C |
| ATOM | 2435 | ND1 | HIS | D | 421 | 36.598 | 74.726 | 65.968 | 1.00 | 7.15 | D | N |
| ATOM | 2436 | CE1 | HIS | D | 421 | 37.025 | 75.664 | 66.794 | 1.00 | 8.00 | D | C |
| ATOM | 2437 | NE2 | HIS | D | 421 | 36.053 | 76.543 | 66.962 | 1.00 | 9.32 | D | N |
| ATOM | 2438 | C | HIS | D | 421 | 33.698 | 73.802 | 62.272 | 1.00 | 9.89 | D | C |
| ATOM | 2439 | O | HIS | D | 421 | 32.516 | 73.949 | 61.941 | 1.00 | 10.23 | D | O |
| ATOM | 2440 | N | ALA | D | 422 | 34.428 | 72.782 | 61.845 | 1.00 | 10.10 | D | N |
| ATOM | 2441 | CA | ALA | D | 422 | 33.839 | 71.786 | 60.961 | 1.00 | 11.59 | D | C |
| ATOM | 2442 | CB | ALA | D | 422 | 34.092 | 72.174 | 59.503 | 1.00 | 13.45 | D | C |
| ATOM | 2443 | C | ALA | D | 422 | 34.383 | 70.394 | 61.234 | 1.00 | 10.06 | D | C |
| ATOM | 2444 | O | ALA | D | 422 | 35.513 | 70.250 | 61.712 | 1.00 | 13.13 | D | O |
| ATOM | 2445 | N | GLU | D | 423 | 33.576 | 69.377 | 60.931 | 1.00 | 8.49 | D | N |
| ATOM | 2446 | CA | GLU | D | 423 | 33.962 | 67.976 | 61.108 | 1.00 | 11.47 | D | C |
| ATOM | 2447 | CB | GLU | D | 423 | 33.019 | 67.272 | 62.101 | 1.00 | 14.24 | D | C |
| ATOM | 2448 | CG | GLU | D | 423 | 32.795 | 67.992 | 63.432 | 1.00 | 13.09 | D | C |
| ATOM | 2449 | CD | GLU | D | 423 | 32.031 | 67.112 | 64.384 | 1.00 | 11.80 | D | C |
| ATOM | 2450 | OE1 | GLU | D | 423 | 32.666 | 66.294 | 65.071 | 1.00 | 14.05 | D | O |
| ATOM | 2451 | OE2 | GLU | D | 423 | 30.792 | 67.209 | 64.426 | 1.00 | 13.84 | D | O |
| ATOM | 2452 | C | GLU | D | 423 | 33.913 | 67.223 | 59.764 | 1.00 | 12.46 | D | C |
| ATOM | 2453 | O | GLU | D | 423 | 33.085 | 66.321 | 59.561 | 1.00 | 13.18 | D | O |
| ATOM | 2454 | N | PRO | D | 424 | 34.805 | 67.579 | 58.830 | 1.00 | 13.81 | D | N |
| ATOM | 2455 | CD | PRO | D | 424 | 35.827 | 68.640 | 58.916 | 1.00 | 11.97 | D | C |
| ATOM | 2456 | CA | PRO | D | 424 | 34.808 | 66.908 | 57.530 | 1.00 | 12.61 | D | C |
| ATOM | 2457 | CB | PRO | D | 424 | 35.876 | 67.659 | 56.736 | 1.00 | 12.24 | D | C |
| ATOM | 2458 | CG | PRO | D | 424 | 36.688 | 68.382 | 57.745 | 1.00 | 12.39 | D | C |
| ATOM | 2459 | C | PRO | D | 424 | 35.040 | 65.401 | 57.526 | 1.00 | 13.27 | D | C |
| ATOM | 2460 | O | PRO | D | 424 | 35.844 | 64.866 | 58.281 | 1.00 | 14.29 | D | O |
| ATOM | 2461 | N | ARG | D | 425 | 34.310 | 64.727 | 56.645 | 1.00 | 14.95 | D | N |
| ATOM | 2462 | CA | ARG | D | 425 | 34.404 | 63.284 | 56.474 | 1.00 | 14.59 | D | C |
| ATOM | 2463 | CB | ARG | D | 425 | 32.987 | 62.699 | 56.295 | 1.00 | 14.13 | D | C |
| ATOM | 2464 | CG | ARG | D | 425 | 32.450 | 61.997 | 57.538 | 1.00 | 16.21 | D | C |
| ATOM | 2465 | CD | ARG | D | 425 | 31.116 | 62.537 | 58.091 | 1.00 | 18.93 | D | C |
| ATOM | 2466 | NE | ARG | D | 425 | 31.279 | 63.764 | 58.851 | 1.00 | 18.29 | D | N |
| ATOM | 2467 | CZ | ARG | D | 425 | 30.482 | 64.188 | 59.836 | 1.00 | 17.02 | D | C |
| ATOM | 2468 | NH1 | ARG | D | 425 | 29.416 | 63.493 | 60.244 | 1.00 | 8.41 | D | N |
| ATOM | 2469 | NH2 | ARG | D | 425 | 30.745 | 65.373 | 60.378 | 1.00 | 13.54 | D | N |
| ATOM | 2470 | C | ARG | D | 425 | 35.301 | 62.949 | 55.257 | 1.00 | 15.77 | D | C |
| ATOM | 2471 | O | ARG | D | 425 | 35.110 | 63.489 | 54.156 | 1.00 | 12.75 | D | O |
| ATOM | 2472 | N | LEU | D | 426 | 36.298 | 62.089 | 55.489 | 1.00 | 13.84 | D | N |
| ATOM | 2473 | CA | LEU | D | 426 | 37.233 | 61.635 | 54.457 | 1.00 | 13.81 | D | C |
| ATOM | 2474 | CB | LEU | D | 426 | 38.684 | 61.661 | 54.975 | 1.00 | 13.27 | D | C |
| ATOM | 2475 | CG | LEU | D | 426 | 39.393 | 62.999 | 55.203 | 1.00 | 13.00 | D | C |
| ATOM | 2476 | CD1 | LEU | D | 426 | 40.711 | 62.767 | 55.943 | 1.00 | 12.15 | D | C |
| ATOM | 2477 | CD2 | LEU | D | 426 | 39.644 | 63.673 | 53.843 | 1.00 | 13.62 | D | C |
| ATOM | 2478 | C | LEU | D | 426 | 36.833 | 60.195 | 54.148 | 1.00 | 16.23 | D | C |
| ATOM | 2479 | O | LEU | D | 426 | 36.357 | 59.478 | 55.038 | 1.00 | 17.74 | D | O |
| ATOM | 2480 | N | SER | D | 427 | 37.036 | 59.763 | 52.903 | 1.00 | 16.43 | D | N |
| ATOM | 2481 | CA | SER | D | 427 | 36.651 | 58.410 | 52.491 | 1.00 | 15.86 | D | C |
| ATOM | 2482 | CB | SER | D | 427 | 36.118 | 58.418 | 51.055 | 1.00 | 14.87 | D | C |
| ATOM | 2483 | OG | SER | D | 427 | 34.958 | 59.210 | 50.935 | 1.00 | 13.31 | D | O |
| ATOM | 2484 | C | SER | D | 427 | 37.678 | 57.299 | 52.569 | 1.00 | 14.15 | D | C |
| ATOM | 2485 | O | SER | D | 427 | 38.827 | 57.466 | 52.176 | 1.00 | 14.21 | D | O |
| ATOM | 2486 | N | ILE | D | 428 | 37.225 | 56.161 | 53.080 | 1.00 | 14.71 | D | N |
| ATOM | 2487 | CA | ILE | D | 428 | 38.014 | 54.935 | 53.159 | 1.00 | 15.31 | D | C |
| ATOM | 2488 | CB | ILE | D | 428 | 38.344 | 54.525 | 54.627 | 1.00 | 14.09 | D | C |
| ATOM | 2489 | CG2 | ILE | D | 428 | 38.645 | 53.033 | 54.701 | 1.00 | 14.17 | D | C |
| ATOM | 2490 | CG1 | ILE | D | 428 | 39.552 | 55.323 | 55.131 | 1.00 | 10.21 | D | C |
| ATOM | 2491 | CD1 | ILE | D | 428 | 40.891 | 54.979 | 54.444 | 1.00 | 10.91 | D | C |
| ATOM | 2492 | C | ILE | D | 428 | 36.968 | 54.012 | 52.555 | 1.00 | 15.23 | D | C |
| ATOM | 2493 | O | ILE | D | 428 | 35.872 | 53.895 | 53.098 | 1.00 | 18.09 | D | O |
| ATOM | 2494 | N | TYR | D | 429 | 37.276 | 53.388 | 51.424 | 1.00 | 16.56 | D | N |
| ATOM | 2495 | CA | TYR | D | 429 | 36.290 | 52.554 | 50.739 | 1.00 | 18.56 | D | C |
| ATOM | 2496 | CB | TYR | D | 429 | 36.474 | 52.702 | 49.224 | 1.00 | 18.70 | D | C |
| ATOM | 2497 | CG | TYR | D | 429 | 36.320 | 54.122 | 48.727 | 1.00 | 16.11 | D | C |
| ATOM | 2498 | CD1 | TYR | D | 429 | 37.418 | 54.975 | 48.640 | 1.00 | 16.56 | D | C |
| ATOM | 2499 | CE1 | TYR | D | 429 | 37.282 | 56.275 | 48.171 | 1.00 | 15.67 | D | C |
| ATOM | 2500 | CD2 | TYR | D | 429 | 35.077 | 54.606 | 48.332 | 1.00 | 15.58 | D | C |
| ATOM | 2501 | CE2 | TYR | D | 429 | 34.929 | 55.906 | 47.861 | 1.00 | 14.93 | D | C |
| ATOM | 2502 | CZ | TYR | D | 429 | 36.031 | 56.729 | 47.782 | 1.00 | 20.43 | D | C |
| ATOM | 2503 | OH | TYR | D | 429 | 35.875 | 58.008 | 47.287 | 1.00 | 28.80 | D | O |
| ATOM | 2504 | C | TYR | D | 429 | 36.204 | 51.070 | 51.071 | 1.00 | 21.80 | D | C |
| ATOM | 2505 | O | TYR | D | 429 | 35.167 | 50.440 | 50.859 | 1.00 | 22.65 | D | O |
| ATOM | 2506 | N | GLY | D | 430 | 37.281 | 50.501 | 51.589 | 1.00 | 23.38 | D | N |
| ATOM | 2507 | CA | GLY | D | 430 | 37.265 | 49.079 | 51.867 | 1.00 | 23.35 | D | C |
| ATOM | 2508 | C | GLY | D | 430 | 37.543 | 48.352 | 50.561 | 1.00 | 22.92 | D | C |
| ATOM | 2509 | O | GLY | D | 430 | 37.339 | 47.149 | 50.459 | 1.00 | 22.50 | D | O |
| ATOM | 2510 | N | ARG | D | 431 | 38.012 | 49.099 | 49.559 | 1.00 | 24.55 | D | N |
| ATOM | 2511 | CA | ARG | D | 431 | 38.322 | 48.549 | 48.237 | 1.00 | 24.93 | D | C |
| ATOM | 2512 | CB | ARG | D | 431 | 38.368 | 49.666 | 47.193 | 1.00 | 27.32 | D | C |
| ATOM | 2513 | CG | ARG | D | 431 | 38.482 | 49.175 | 45.748 | 1.00 | 30.38 | D | C |
| ATOM | 2514 | CD | ARG | D | 431 | 39.034 | 50.265 | 44.840 | 1.00 | 32.66 | D | C |
| ATOM | 2515 | NE | ARG | D | 431 | 40.180 | 50.956 | 45.431 | 1.00 | 33.51 | D | N |
| ATOM | 2516 | CZ | ARG | D | 431 | 40.130 | 52.190 | 45.918 | 1.00 | 35.48 | D | C |
| ATOM | 2517 | NH1 | ARG | D | 431 | 38.992 | 52.870 | 45.886 | 1.00 | 39.25 | D | N |
| ATOM | 2518 | NH2 | ARG | D | 431 | 41.215 | 52.754 | 46.422 | 1.00 | 35.08 | D | N |
| ATOM | 2519 | C | ARG | D | 431 | 39.664 | 47.846 | 48.268 | 1.00 | 24.72 | D | C |
| ATOM | 2520 | O | ARG | D | 431 | 39.839 | 46.782 | 47.675 | 1.00 | 25.84 | D | O |
| ATOM | 2521 | N | SER | D | 432 | 40.612 | 48.451 | 48.967 | 1.00 | 25.25 | D | N |
| ATOM | 2522 | CA | SER | D | 432 | 41.942 | 47.891 | 49.075 | 1.00 | 25.67 | D | C |
| ATOM | 2523 | CB | SER | D | 432 | 42.867 | 48.556 | 48.058 | 1.00 | 24.88 | D | C |
| ATOM | 2524 | OG | SER | D | 432 | 44.198 | 48.488 | 48.512 | 1.00 | 27.51 | D | O |
| ATOM | 2525 | C | SER | D | 432 | 42.496 | 48.090 | 50.480 | 1.00 | 26.34 | D | C |
| ATOM | 2526 | O | SER | D | 432 | 42.185 | 49.069 | 51.158 | 1.00 | 24.32 | D | O |
| ATOM | 2527 | N | PRO | D | 433 | 43.343 | 47.161 | 50.935 | 1.00 | 29.08 | D | N |
| ATOM | 2528 | CD | PRO | D | 433 | 43.802 | 45.940 | 50.247 | 1.00 | 29.09 | D | C |
| ATOM | 2529 | CA | PRO | D | 433 | 43.912 | 47.293 | 52.283 | 1.00 | 28.30 | D | C |
| ATOM | 2530 | CB | PRO | D | 433 | 44.555 | 45.930 | 52.545 | 1.00 | 28.15 | D | C |
| ATOM | 2531 | CG | PRO | D | 433 | 44.845 | 45.378 | 51.189 | 1.00 | 27.60 | D | C |
| ATOM | 2532 | C | PRO | D | 433 | 44.904 | 48.440 | 52.451 | 1.00 | 26.29 | D | C |
| ATOM | 2533 | O | PRO | D | 433 | 45.141 | 48.889 | 53.572 | 1.00 | 28.79 | D | O |
| ATOM | 2534 | N | ASP | D | 434 | 45.460 | 48.937 | 51.352 | 1.00 | 22.52 | D | N |
| ATOM | 2535 | CA | ASP | D | 434 | 46.437 | 50.015 | 51.435 | 1.00 | 21.86 | D | C |
| ATOM | 2536 | CB | ASP | D | 434 | 47.441 | 49.911 | 50.267 | 1.00 | 29.53 | D | C |
| ATOM | 2537 | CG | ASP | D | 434 | 46.847 | 50.338 | 48.903 | 1.00 | 41.48 | D | C |
| ATOM | 2538 | OD1 | ASP | D | 434 | 45.603 | 50.435 | 48.771 | 1.00 | 48.99 | D | O |
| ATOM | 2539 | OD2 | ASP | D | 434 | 47.632 | 50.578 | 47.945 | 1.00 | 44.53 | D | O |
| ATOM | 2540 | C | ASP | D | 434 | 45.864 | 51.428 | 51.516 | 1.00 | 19.51 | D | C |
| ATOM | 2541 | O | ASP | D | 434 | 46.620 | 52.398 | 51.581 | 1.00 | 20.01 | D | O |
| ATOM | 2542 | N | GLU | D | 435 | 44.539 | 51.551 | 51.547 | 1.00 | 16.27 | D | N |
| ATOM | 2543 | CA | GLU | D | 435 | 43.900 | 52.866 | 51.598 | 1.00 | 14.81 | D | C |
| ATOM | 2544 | CB | GLU | D | 435 | 42.384 | 52.716 | 51.541 | 1.00 | 15.12 | D | C |
| ATOM | 2545 | CG | GLU | D | 435 | 41.867 | 52.208 | 50.229 | 1.00 | 15.91 | D | C |
| ATOM | 2546 | CD | GLU | D | 435 | 40.367 | 52.297 | 50.124 | 1.00 | 19.83 | D | C |
| ATOM | 2547 | OE1 | GLU | D | 435 | 39.749 | 51.261 | 49.799 | 1.00 | 16.80 | D | O |
| ATOM | 2548 | OE2 | GLU | D | 435 | 39.811 | 53.402 | 50.359 | 1.00 | 17.10 | D | O |
| ATOM | 2549 | C | GLU | D | 435 | 44.268 | 53.668 | 52.836 | 1.00 | 16.13 | D | C |
| ATOM | 2550 | O | GLU | D | 435 | 44.464 | 54.885 | 52.775 | 1.00 | 17.79 | D | O |
| ATOM | 2551 | N | TRP | D | 436 | 44.353 | 52.991 | 53.974 | 1.00 | 16.69 | D | N |
| ATOM | 2552 | CA | TRP | D | 436 | 44.688 | 53.676 | 55.217 | 1.00 | 17.37 | D | C |
| ATOM | 2553 | CB | TRP | D | 436 | 44.572 | 52.702 | 56.398 | 1.00 | 15.71 | D | C |
| ATOM | 2554 | CG | TRP | D | 436 | 43.160 | 52.500 | 56.848 | 1.00 | 11.94 | D | C |
| ATOM | 2555 | CD2 | TRP | D | 436 | 42.384 | 53.407 | 57.641 | 1.00 | 11.12 | D | C |
| ATOM | 2556 | CE2 | TRP | D | 436 | 41.121 | 52.811 | 57.838 | 1.00 | 11.03 | D | C |
| ATOM | 2557 | CE3 | TRP | D | 436 | 42.639 | 54.664 | 58.206 | 1.00 | 10.70 | D | C |
| ATOM | 2558 | CD1 | TRP | D | 436 | 42.362 | 51.425 | 56.600 | 1.00 | 11.02 | D | C |
| ATOM | 2559 | NE1 | TRP | D | 436 | 41.133 | 51.602 | 57.193 | 1.00 | 11.16 | D | N |
| ATOM | 2560 | CZ2 | TRP | D | 436 | 40.103 | 53.435 | 58.583 | 1.00 | 11.43 | D | C |
| ATOM | 2561 | CZ3 | TRP | D | 436 | 41.631 | 55.278 | 58.946 | 1.00 | 13.39 | D | C |
| ATOM | 2562 | CH2 | TRP | D | 436 | 40.376 | 54.658 | 59.125 | 1.00 | 6.93 | D | C |
| ATOM | 2563 | C | TRP | D | 436 | 46.098 | 54.228 | 55.122 | 1.00 | 17.87 | D | C |
| ATOM | 2564 | O | TRP | D | 436 | 46.368 | 55.373 | 55.507 | 1.00 | 19.41 | D | O |
| ATOM | 2565 | N | SER | D | 437 | 46.998 | 53.411 | 54.591 | 1.00 | 18.09 | D | N |
| ATOM | 2566 | CA | SER | D | 437 | 48.390 | 53.824 | 54.441 | 1.00 | 19.91 | D | C |
| ATOM | 2567 | CB | SER | D | 437 | 49.217 | 52.684 | 53.832 | 1.00 | 21.25 | D | C |
| ATOM | 2568 | OG | SER | D | 437 | 50.544 | 53.121 | 53.606 | 1.00 | 27.86 | D | O |
| ATOM | 2569 | C | SER | D | 437 | 48.495 | 55.065 | 53.559 | 1.00 | 17.19 | D | C |
| ATOM | 2570 | O | SER | D | 437 | 49.211 | 56.017 | 53.881 | 1.00 | 17.65 | D | O |
| ATOM | 2571 | N | LYS | D | 438 | 47.763 | 55.059 | 52.452 | 1.00 | 17.03 | D | N |
| ATOM | 2572 | CA | LYS | D | 438 | 47.791 | 56.186 | 51.537 | 1.00 | 17.65 | D | C |
| ATOM | 2573 | CB | LYS | D | 438 | 47.108 | 55.814 | 50.221 | 1.00 | 20.44 | D | C |
| ATOM | 2574 | CG | LYS | D | 438 | 47.843 | 54.735 | 49.443 | 1.00 | 22.73 | D | C |
| ATOM | 2575 | CD | LYS | D | 438 | 47.749 | 54.968 | 47.949 | 1.00 | 26.54 | D | C |
| ATOM | 2576 | CE | LYS | D | 438 | 47.491 | 53.657 | 47.233 | 1.00 | 30.37 | D | C |
| ATOM | 2577 | NZ | LYS | D | 438 | 47.508 | 53.811 | 45.760 | 1.00 | 35.25 | D | N |
| ATOM | 2578 | C | LYS | D | 438 | 47.143 | 57.429 | 52.118 | 1.00 | 18.55 | D | C |
| ATOM | 2579 | O | LYS | D | 438 | 47.674 | 58.537 | 51.969 | 1.00 | 19.01 | D | O |
| ATOM | 2580 | N | LEU | D | 439 | 46.002 | 57.259 | 52.784 | 1.00 | 18.11 | D | N |
| ATOM | 2581 | CA | LEU | D | 439 | 45.307 | 58.410 | 53.359 | 1.00 | 16.64 | D | C |
| ATOM | 2582 | CB | LEU | D | 439 | 43.897 | 58.008 | 53.840 | 1.00 | 17.59 | D | C |
| ATOM | 2583 | CG | LEU | D | 439 | 42.943 | 59.131 | 54.282 | 1.00 | 16.54 | D | C |
| ATOM | 2584 | CD1 | LEU | D | 439 | 42.764 | 60.156 | 53.169 | 1.00 | 15.54 | D | C |
| ATOM | 2585 | CD2 | LEU | D | 439 | 41.588 | 58.519 | 54.677 | 1.00 | 15.25 | D | C |
| ATOM | 2586 | C | LEU | D | 439 | 46.093 | 59.052 | 54.494 | 1.00 | 16.69 | D | C |
| ATOM | 2587 | O | LEU | D | 439 | 46.167 | 60.287 | 54.572 | 1.00 | 17.86 | D | O |
| ATOM | 2588 | N | SER | D | 440 | 46.679 | 58.239 | 55.376 | 1.00 | 15.68 | D | N |
| ATOM | 2589 | CA | SER | D | 440 | 47.455 | 58.801 | 56.484 | 1.00 | 15.72 | D | C |
| ATOM | 2590 | CB | SER | D | 440 | 47.938 | 57.715 | 57.451 | 1.00 | 15.76 | D | C |
| ATOM | 2591 | OG | SER | D | 440 | 48.420 | 56.573 | 56.780 | 1.00 | 19.16 | D | O |
| ATOM | 2592 | C | SER | D | 440 | 48.655 | 59.575 | 55.970 | 1.00 | 15.74 | D | C |
| ATOM | 2593 | O | SER | D | 440 | 49.001 | 60.623 | 56.524 | 1.00 | 15.10 | D | O |
| ATOM | 2594 | N | SER | D | 441 | 49.295 | 59.060 | 54.919 | 1.00 | 17.73 | D | N |
| ATOM | 2595 | CA | SER | D | 441 | 50.459 | 59.738 | 54.322 | 1.00 | 21.99 | D | C |
| ATOM | 2596 | CB | SER | D | 441 | 51.116 | 58.858 | 53.253 | 1.00 | 23.34 | D | C |
| ATOM | 2597 | OG | SER | D | 441 | 51.726 | 57.716 | 53.842 | 1.00 | 26.63 | D | O |
| ATOM | 2598 | C | SER | D | 441 | 50.032 | 61.057 | 53.690 | 1.00 | 20.50 | D | C |
| ATOM | 2599 | O | SER | D | 441 | 50.729 | 62.066 | 53.801 | 1.00 | 22.09 | D | O |
| ATOM | 2600 | N | TRP | D | 442 | 48.880 | 61.034 | 53.020 | 1.00 | 21.49 | D | N |
| ATOM | 2601 | CA | TRP | D | 442 | 48.324 | 62.225 | 52.389 | 1.00 | 18.54 | D | C |
| ATOM | 2602 | CB | TRP | D | 442 | 47.000 | 61.865 | 51.688 | 1.00 | 18.66 | D | C |
| ATOM | 2603 | CG | TRP | D | 442 | 46.207 | 63.072 | 51.194 | 1.00 | 21.35 | D | C |
| ATOM | 2604 | CD2 | TRP | D | 442 | 45.091 | 63.716 | 51.847 | 1.00 | 22.09 | D | C |
| ATOM | 2605 | CE2 | TRP | D | 442 | 44.701 | 64.806 | 51.030 | 1.00 | 21.01 | D | C |
| ATOM | 2606 | CE3 | TRP | D | 442 | 44.384 | 63.477 | 53.036 | 1.00 | 23.42 | D | C |
| ATOM | 2607 | CD1 | TRP | D | 442 | 46.433 | 63.779 | 50.051 | 1.00 | 20.88 | D | C |
| ATOM | 2608 | NE1 | TRP | D | 442 | 45.537 | 64.820 | 49.945 | 1.00 | 22.75 | D | N |
| ATOM | 2609 | CZ2 | TRP | D | 442 | 43.637 | 65.662 | 51.365 | 1.00 | 20.07 | D | C |
| ATOM | 2610 | CZ3 | TRP | D | 442 | 43.317 | 64.335 | 53.367 | 1.00 | 22.28 | D | C |
| ATOM | 2611 | CH2 | TRP | D | 442 | 42.963 | 65.410 | 52.531 | 1.00 | 20.67 | D | C |
| ATOM | 2612 | C | TRP | D | 442 | 48.082 | 63.307 | 53.451 | 1.00 | 18.57 | D | C |
| ATOM | 2613 | O | TRP | D | 442 | 48.456 | 64.470 | 53.283 | 1.00 | 17.16 | D | O |
| ATOM | 2614 | N | PHE | D | 443 | 47.460 | 62.898 | 54.552 | 1.00 | 18.32 | D | N |
| ATOM | 2615 | CA | PHE | D | 443 | 47.122 | 63.799 | 55.639 | 1.00 | 17.80 | D | C |
| ATOM | 2616 | CB | PHE | D | 443 | 46.205 | 63.058 | 56.631 | 1.00 | 20.03 | D | C |
| ATOM | 2617 | CG | PHE | D | 443 | 45.612 | 63.941 | 57.704 | 1.00 | 20.78 | D | C |
| ATOM | 2618 | CD1 | PHE | D | 443 | 46.315 | 64.213 | 58.879 | 1.00 | 20.78 | D | C |
| ATOM | 2619 | CD2 | PHE | D | 443 | 44.345 | 64.491 | 57.547 | 1.00 | 19.31 | D | C |
| ATOM | 2620 | CE1 | PHE | D | 443 | 45.759 | 65.022 | 59.875 | 1.00 | 21.27 | D | C |
| ATOM | 2621 | CE2 | PHE | D | 443 | 43.785 | 65.299 | 58.542 | 1.00 | 20.29 | D | C |
| ATOM | 2622 | CZ | PHE | D | 443 | 44.494 | 65.563 | 59.705 | 1.00 | 19.58 | D | C |
| ATOM | 2623 | C | PHE | D | 443 | 48.346 | 64.358 | 56.365 | 1.00 | 18.59 | D | C |
| ATOM | 2624 | O | PHE | D | 443 | 48.439 | 65.563 | 56.600 | 1.00 | 20.50 | D | O |
| ATOM | 2625 | N | VAL | D | 444 | 49.281 | 63.488 | 56.728 | 1.00 | 18.53 | D | N |
| ATOM | 2626 | CA | VAL | D | 444 | 50.467 | 63.915 | 57.459 | 1.00 | 20.43 | D | C |
| ATOM | 2627 | CB | VAL | D | 444 | 51.208 | 62.701 | 58.042 | 1.00 | 22.38 | D | C |
| ATOM | 2628 | CG1 | VAL | D | 444 | 52.466 | 63.141 | 58.751 | 1.00 | 20.74 | D | C |
| ATOM | 2629 | CG2 | VAL | D | 444 | 50.300 | 61.962 | 58.999 | 1.00 | 23.71 | D | C |
| ATOM | 2630 | C | VAL | D | 444 | 51.426 | 64.719 | 56.598 | 1.00 | 22.51 | D | C |
| ATOM | 2631 | O | VAL | D | 444 | 51.869 | 65.799 | 56.986 | 1.00 | 22.37 | D | O |
| ATOM | 2632 | N | ARG | D | 445 | 51.732 | 64.198 | 55.416 | 1.00 | 25.12 | D | N |
| ATOM | 2633 | CA | ARG | D | 445 | 52.645 | 64.878 | 54.505 | 1.00 | 25.86 | D | C |
| ATOM | 2634 | CB | ARG | D | 445 | 52.896 | 64.014 | 53.279 | 1.00 | 28.18 | D | C |
| ATOM | 2635 | CG | ARG | D | 445 | 54.014 | 63.016 | 53.499 | 1.00 | 37.25 | D | C |
| ATOM | 2636 | CD | ARG | D | 445 | 53.740 | 61.710 | 52.788 | 1.00 | 40.09 | D | C |
| ATOM | 2637 | NE | ARG | D | 445 | 54.370 | 60.590 | 53.473 | 1.00 | 43.79 | D | N |
| ATOM | 2638 | CZ | ARG | D | 445 | 55.029 | 59.623 | 52.847 | 1.00 | 47.28 | D | C |
| ATOM | 2639 | NH1 | ARG | D | 445 | 55.138 | 59.651 | 51.525 | 1.00 | 48.87 | D | N |
| ATOM | 2640 | NH2 | ARG | D | 445 | 55.574 | 58.629 | 53.536 | 1.00 | 46.96 | D | N |
| ATOM | 2641 | C | ARG | D | 445 | 52.168 | 66.258 | 54.072 | 1.00 | 25.23 | D | C |
| ATOM | 2642 | O | ARG | D | 445 | 52.966 | 67.177 | 53.928 | 1.00 | 26.24 | D | O |
| ATOM | 2643 | N | ASN | D | 446 | 50.872 | 66.419 | 53.848 | 1.00 | 24.39 | D | N |
| ATOM | 2644 | CA | ASN | D | 446 | 50.374 | 67.734 | 53.447 | 1.00 | 22.88 | D | C |
| ATOM | 2645 | CB | ASN | D | 446 | 49.095 | 67.584 | 52.621 | 1.00 | 20.64 | D | C |
| ATOM | 2646 | CG | ASN | D | 446 | 49.359 | 67.064 | 51.215 | 1.00 | 19.73 | D | C |
| ATOM | 2647 | OD1 | ASN | D | 446 | 49.139 | 65.887 | 50.923 | 1.00 | 22.68 | D | O |
| ATOM | 2648 | ND2 | ASN | D | 446 | 49.823 | 67.941 | 50.337 | 1.00 | 19.31 | D | N |
| ATOM | 2649 | C | ASN | D | 446 | 50.112 | 68.588 | 54.698 | 1.00 | 23.93 | D | C |
| ATOM | 2650 | O | ASN | D | 446 | 49.689 | 69.744 | 54.609 | 1.00 | 21.22 | D | O |
| ATOM | 2651 | N | ARG | D | 447 | 50.376 | 68.009 | 55.868 | 1.00 | 24.62 | D | N |
| ATOM | 2652 | CA | ARG | D | 447 | 50.162 | 68.702 | 57.137 | 1.00 | 27.35 | D | C |
| ATOM | 2653 | CB | ARG | D | 447 | 51.196 | 69.824 | 57.339 | 1.00 | 27.50 | D | C |
| ATOM | 2654 | CG | ARG | D | 447 | 52.606 | 69.479 | 56.862 | 1.00 | 34.53 | D | C |
| ATOM | 2655 | CD | ARG | D | 447 | 53.546 | 69.076 | 57.994 | 1.00 | 35.08 | D | C |
| ATOM | 2656 | NE | ARG | D | 447 | 53.620 | 70.089 | 59.047 | 1.00 | 39.33 | D | N |
| ATOM | 2657 | CZ | ARG | D | 447 | 54.019 | 69.844 | 60.295 | 1.00 | 42.72 | D | C |
| ATOM | 2658 | NH1 | ARG | D | 447 | 54.384 | 68.618 | 60.653 | 1.00 | 43.37 | D | N |
| ATOM | 2659 | NH2 | ARG | D | 447 | 54.039 | 70.817 | 61.199 | 1.00 | 44.17 | D | N |
| ATOM | 2660 | C | ARG | D | 447 | 48.759 | 69.294 | 57.179 | 1.00 | 26.97 | D | C |
| ATOM | 2661 | O | ARG | D | 447 | 48.579 | 70.507 | 57.313 | 1.00 | 26.85 | D | O |
| ATOM | 2662 | N | ILE | D | 448 | 47.762 | 68.433 | 57.034 | 1.00 | 26.47 | D | N |
| ATOM | 2663 | CA | ILE | D | 448 | 46.386 | 68.884 | 57.074 | 1.00 | 26.36 | D | C |
| ATOM | 2664 | CB | ILE | D | 448 | 45.455 | 67.913 | 56.310 | 1.00 | 24.51 | D | C |
| ATOM | 2665 | CG2 | ILE | D | 448 | 44.000 | 68.232 | 56.589 | 1.00 | 23.38 | D | C |
| ATOM | 2666 | CG1 | ILE | D | 448 | 45.711 | 68.036 | 54.809 | 1.00 | 25.29 | D | C |
| ATOM | 2667 | CD1 | ILE | D | 448 | 45.783 | 66.714 | 54.120 | 1.00 | 28.39 | D | C |
| ATOM | 2668 | C | ILE | D | 448 | 46.074 | 68.891 | 58.563 | 1.00 | 28.84 | D | C |
| ATOM | 2669 | O | ILE | D | 448 | 46.116 | 67.868 | 59.241 | 1.00 | 34.42 | D | O |
| ATOM | 2670 | N | TYR | D | 449 | 45.820 | 70.063 | 59.091 | 1.00 | 28.30 | D | N |
| ATOM | 2671 | CA | TYR | D | 449 | 45.517 | 70.183 | 60.498 | 1.00 | 26.63 | D | C |
| ATOM | 2672 | CB | TYR | D | 449 | 46.712 | 69.803 | 61.376 | 1.00 | 26.09 | D | C |
| ATOM | 2673 | CG | TYR | D | 449 | 46.559 | 70.390 | 62.755 | 1.00 | 27.49 | D | C |
| ATOM | 2674 | CD1 | TYR | D | 449 | 45.808 | 69.737 | 63.735 | 1.00 | 25.88 | D | C |
| ATOM | 2675 | CE1 | TYR | D | 449 | 45.482 | 70.369 | 64.935 | 1.00 | 26.87 | D | C |
| ATOM | 2676 | CD2 | TYR | D | 449 | 46.999 | 71.687 | 63.023 | 1.00 | 29.80 | D | C |
| ATOM | 2677 | CE2 | TYR | D | 449 | 46.680 | 72.326 | 64.213 | 1.00 | 30.83 | D | C |
| ATOM | 2678 | CZ | TYR | D | 449 | 45.916 | 71.668 | 65.160 | 1.00 | 30.47 | D | C |
| ATOM | 2679 | OH | TYR | D | 449 | 45.557 | 72.338 | 66.308 | 1.00 | 36.02 | D | O |
| ATOM | 2680 | C | TYR | D | 449 | 45.210 | 71.644 | 60.670 | 1.00 | 25.03 | D | C |
| ATOM | 2681 | O | TYR | D | 449 | 46.051 | 72.499 | 60.382 | 1.00 | 26.51 | D | O |
| ATOM | 2682 | N | SER | D | 450 | 43.997 | 71.927 | 61.118 | 1.00 | 22.33 | D | N |
| ATOM | 2683 | CA | SER | D | 450 | 43.558 | 73.294 | 61.315 | 1.00 | 19.71 | D | C |
| ATOM | 2684 | CB | SER | D | 450 | 42.466 | 73.651 | 60.282 | 1.00 | 16.65 | D | C |
| ATOM | 2685 | OG | SER | D | 450 | 41.620 | 74.727 | 60.703 | 1.00 | 23.60 | D | O |
| ATOM | 2686 | C | SER | D | 450 | 42.991 | 73.232 | 62.715 | 1.00 | 21.30 | D | C |
| ATOM | 2687 | O | SER | D | 450 | 42.483 | 72.192 | 63.146 | 1.00 | 20.80 | D | O |
| ATOM | 2688 | N | SER | D | 451 | 43.098 | 74.326 | 63.448 | 1.00 | 21.09 | D | N |
| ATOM | 2689 | CA | SER | D | 451 | 42.566 | 74.344 | 64.798 | 1.00 | 20.34 | D | C |
| ATOM | 2690 | CB | SER | D | 451 | 43.136 | 75.525 | 65.566 | 1.00 | 21.21 | D | C |
| ATOM | 2691 | OG | SER | D | 451 | 42.779 | 76.722 | 64.906 | 1.00 | 23.88 | D | O |
| ATOM | 2692 | C | SER | D | 451 | 41.053 | 74.449 | 64.756 | 1.00 | 18.33 | D | C |
| ATOM | 2693 | O | SER | D | 451 | 40.407 | 74.387 | 65.793 | 1.00 | 20.39 | D | O |
| ATOM | 2694 | N | ASN | D | 452 | 40.481 | 74.602 | 63.564 | 1.00 | 16.56 | D | N |
| ATOM | 2695 | CA | ASN | D | 452 | 39.032 | 74.704 | 63.446 | 1.00 | 13.14 | D | C |
| ATOM | 2696 | CB | ASN | D | 452 | 38.630 | 76.032 | 62.813 | 1.00 | 12.84 | D | C |
| ATOM | 2697 | CG | ASN | D | 452 | 38.764 | 77.196 | 63.783 | 1.00 | 14.85 | D | C |
| ATOM | 2698 | OD1 | ASN | D | 452 | 39.855 | 77.484 | 64.264 | 1.00 | 17.73 | D | O |
| ATOM | 2699 | ND2 | ASN | D | 452 | 37.652 | 77.866 | 64.078 | 1.00 | 15.05 | D | N |
| ATOM | 2700 | C | ASN | D | 452 | 38.398 | 73.561 | 62.679 | 1.00 | 11.56 | D | C |
| ATOM | 2701 | O | ASN | D | 452 | 37.274 | 73.680 | 62.200 | 1.00 | 11.40 | D | O |
| ATOM | 2702 | N | MET | D | 453 | 39.119 | 72.455 | 62.577 | 1.00 | 10.91 | D | N |
| ATOM | 2703 | CA | MET | D | 453 | 38.609 | 71.284 | 61.890 | 1.00 | 12.52 | D | C |
| ATOM | 2704 | CB | MET | D | 453 | 39.186 | 71.197 | 60.471 | 1.00 | 14.08 | D | C |
| ATOM | 2705 | CG | MET | D | 453 | 38.567 | 72.121 | 59.448 | 1.00 | 17.73 | D | C |
| ATOM | 2706 | SD | MET | D | 453 | 39.278 | 71.838 | 57.810 | 1.00 | 23.18 | D | S |
| ATOM | 2707 | CE | MET | D | 453 | 37.938 | 72.376 | 56.774 | 1.00 | 22.04 | D | C |
| ATOM | 2708 | C | MET | D | 453 | 39.021 | 70.018 | 62.632 | 1.00 | 14.55 | D | C |
| ATOM | 2709 | O | MET | D | 453 | 40.155 | 69.913 | 63.096 | 1.00 | 16.22 | D | O |
| ATOM | 2710 | N | THR | D | 454 | 38.097 | 69.072 | 62.763 | 1.00 | 13.89 | D | N |
| ATOM | 2711 | CA | THR | D | 454 | 38.409 | 67.777 | 63.365 | 1.00 | 14.59 | D | C |
| ATOM | 2712 | CB | THR | D | 454 | 37.680 | 67.504 | 64.728 | 1.00 | 15.59 | D | C |
| ATOM | 2713 | OG1 | THR | D | 454 | 36.287 | 67.821 | 64.632 | 1.00 | 15.78 | D | O |
| ATOM | 2714 | CG2 | THR | D | 454 | 38.328 | 68.339 | 65.838 | 1.00 | 14.21 | D | C |
| ATOM | 2715 | C | THR | D | 454 | 37.948 | 66.818 | 62.267 | 1.00 | 13.98 | D | C |
| ATOM | 2716 | O | THR | D | 454 | 37.119 | 67.197 | 61.429 | 1.00 | 13.78 | D | O |
| ATOM | 2717 | N | TRP | D | 455 | 38.476 | 65.599 | 62.268 | 1.00 | 13.23 | D | N |
| ATOM | 2718 | CA | TRP | D | 455 | 38.207 | 64.657 | 61.186 | 1.00 | 16.04 | D | C |
| ATOM | 2719 | CB | TRP | D | 455 | 39.539 | 64.351 | 60.460 | 1.00 | 13.75 | D | C |
| ATOM | 2720 | CG | TRP | D | 455 | 40.194 | 65.608 | 59.930 | 1.00 | 14.30 | D | C |
| ATOM | 2721 | CD2 | TRP | D | 455 | 39.988 | 66.196 | 58.635 | 1.00 | 15.35 | D | C |
| ATOM | 2722 | CE2 | TRP | D | 455 | 40.677 | 67.431 | 58.618 | 1.00 | 16.36 | D | C |
| ATOM | 2723 | CE3 | TRP | D | 455 | 39.283 | 65.799 | 57.490 | 1.00 | 14.20 | D | C |
| ATOM | 2724 | CD1 | TRP | D | 455 | 40.988 | 66.480 | 60.623 | 1.00 | 13.99 | D | C |
| ATOM | 2725 | NE1 | TRP | D | 455 | 41.281 | 67.584 | 59.842 | 1.00 | 15.74 | D | N |
| ATOM | 2726 | CZ2 | TRP | D | 455 | 40.680 | 68.274 | 57.494 | 1.00 | 15.13 | D | C |
| ATOM | 2727 | CZ3 | TRP | D | 455 | 39.286 | 66.636 | 56.375 | 1.00 | 14.75 | D | C |
| ATOM | 2728 | CH2 | TRP | D | 455 | 39.978 | 67.855 | 56.389 | 1.00 | 12.80 | D | C |
| ATOM | 2729 | C | TRP | D | 455 | 37.504 | 63.358 | 61.486 | 1.00 | 16.65 | D | C |
| ATOM | 2730 | O | TRP | D | 455 | 37.637 | 62.800 | 62.567 | 1.00 | 19.60 | D | O |
| ATOM | 2731 | N | MET | D | 456 | 36.769 | 62.875 | 60.489 | 1.00 | 16.50 | D | N |
| ATOM | 2732 | CA | MET | D | 456 | 36.051 | 61.618 | 60.589 | 1.00 | 16.13 | D | C |
| ATOM | 2733 | CB | MET | D | 456 | 34.555 | 61.866 | 60.758 | 1.00 | 16.06 | D | C |
| ATOM | 2734 | CG | MET | D | 456 | 34.199 | 62.540 | 62.068 | 1.00 | 12.86 | D | C |
| ATOM | 2735 | SD | MET | D | 456 | 32.433 | 62.804 | 62.213 | 1.00 | 18.93 | D | S |
| ATOM | 2736 | CE | MET | D | 456 | 31.781 | 61.099 | 61.899 | 1.00 | 11.91 | D | C |
| ATOM | 2737 | C | MET | D | 456 | 36.292 | 60.842 | 59.305 | 1.00 | 16.85 | D | C |
| ATOM | 2738 | O | MET | D | 456 | 36.773 | 61.392 | 58.318 | 1.00 | 17.09 | D | O |
| ATOM | 2739 | N | ILE | D | 457 | 35.976 | 59.557 | 59.327 | 1.00 | 16.90 | D | N |
| ATOM | 2740 | CA | ILE | D | 457 | 36.141 | 58.725 | 58.150 | 1.00 | 16.40 | D | C |
| ATOM | 2741 | CB | ILE | D | 457 | 37.133 | 57.554 | 58.415 | 1.00 | 16.58 | D | C |
| ATOM | 2742 | CG2 | ILE | D | 457 | 36.902 | 56.413 | 57.449 | 1.00 | 11.27 | D | C |
| ATOM | 2743 | CG1 | ILE | D | 457 | 38.563 | 58.047 | 58.187 | 1.00 | 20.09 | D | C |
| ATOM | 2744 | CD1 | ILE | D | 457 | 39.345 | 58.090 | 59.418 | 1.00 | 22.94 | D | C |
| ATOM | 2745 | C | ILE | D | 457 | 34.773 | 58.180 | 57.781 | 1.00 | 15.71 | D | C |
| ATOM | 2746 | O | ILE | D | 457 | 34.030 | 57.715 | 58.637 | 1.00 | 15.68 | D | O |
| ATOM | 2747 | N | GLN | D | 458 | 34.419 | 58.286 | 56.507 | 1.00 | 15.78 | D | N |
| ATOM | 2748 | CA | GLN | D | 458 | 33.144 | 57.743 | 56.064 | 1.00 | 14.49 | D | C |
| ATOM | 2749 | CB | GLN | D | 458 | 32.354 | 58.778 | 55.275 | 1.00 | 12.07 | D | C |
| ATOM | 2750 | CG | GLN | D | 458 | 33.007 | 59.176 | 53.963 | 1.00 | 16.80 | D | C |
| ATOM | 2751 | CD | GLN | D | 458 | 32.250 | 60.282 | 53.245 | 1.00 | 21.18 | D | C |
| ATOM | 2752 | OE1 | GLN | D | 458 | 31.471 | 61.024 | 53.852 | 1.00 | 18.97 | D | O |
| ATOM | 2753 | NE2 | GLN | D | 458 | 32.477 | 60.398 | 51.945 | 1.00 | 21.28 | D | N |
| ATOM | 2754 | C | GLN | D | 458 | 33.444 | 56.555 | 55.169 | 1.00 | 13.42 | D | C |
| ATOM | 2755 | O | GLN | D | 458 | 34.371 | 56.606 | 54.360 | 1.00 | 12.92 | D | O |
| ATOM | 2756 | N | VAL | D | 459 | 32.708 | 55.468 | 55.349 | 1.00 | 11.67 | D | N |
| ATOM | 2757 | CA | VAL | D | 459 | 32.900 | 54.346 | 54.474 | 1.00 | 14.12 | D | C |
| ATOM | 2758 | CB | VAL | D | 459 | 33.456 | 53.068 | 55.199 | 1.00 | 17.71 | D | C |
| ATOM | 2759 | CG1 | VAL | D | 459 | 34.069 | 53.444 | 56.537 | 1.00 | 21.26 | D | C |
| ATOM | 2760 | CG2 | VAL | D | 459 | 32.420 | 52.008 | 55.312 | 1.00 | 19.35 | D | C |
| ATOM | 2761 | C | VAL | D | 459 | 31.567 | 54.127 | 53.780 | 1.00 | 14.74 | D | C |
| ATOM | 2762 | O | VAL | D | 459 | 30.550 | 53.838 | 54.400 | 1.00 | 12.74 | D | O |
| ATOM | 2763 | N | PRO | D | 460 | 31.551 | 54.360 | 52.463 | 1.00 | 16.31 | D | N |
| ATOM | 2764 | CD | PRO | D | 460 | 32.722 | 54.834 | 51.696 | 1.00 | 16.92 | D | C |
| ATOM | 2765 | CA | PRO | D | 460 | 30.360 | 54.209 | 51.619 | 1.00 | 13.54 | D | C |
| ATOM | 2766 | CB | PRO | D | 460 | 30.824 | 54.726 | 50.248 | 1.00 | 14.70 | D | C |
| ATOM | 2767 | CG | PRO | D | 460 | 32.086 | 55.549 | 50.538 | 1.00 | 16.59 | D | C |
| ATOM | 2768 | C | PRO | D | 460 | 29.888 | 52.769 | 51.570 | 1.00 | 13.43 | D | C |
| ATOM | 2769 | O | PRO | D | 460 | 30.699 | 51.851 | 51.528 | 1.00 | 15.88 | D | O |
| ATOM | 2770 | N | ARG | D | 461 | 28.576 | 52.566 | 51.585 | 1.00 | 13.61 | D | N |
| ATOM | 2771 | CA | ARG | D | 461 | 28.027 | 51.216 | 51.536 | 1.00 | 16.73 | D | C |
| ATOM | 2772 | CB | ARG | D | 461 | 26.671 | 51.172 | 52.248 | 1.00 | 14.82 | D | C |
| ATOM | 2773 | CG | ARG | D | 461 | 26.683 | 51.778 | 53.664 | 1.00 | 16.64 | D | C |
| ATOM | 2774 | CD | ARG | D | 461 | 25.387 | 51.463 | 54.423 | 1.00 | 15.31 | D | C |
| ATOM | 2775 | NE | ARG | D | 461 | 24.245 | 52.223 | 53.913 | 1.00 | 15.89 | D | N |
| ATOM | 2776 | CZ | ARG | D | 461 | 23.996 | 53.501 | 54.197 | 1.00 | 13.88 | D | C |
| ATOM | 2777 | NH1 | ARG | D | 461 | 24.802 | 54.185 | 54.998 | 1.00 | 14.86 | D | N |
| ATOM | 2778 | NH2 | ARG | D | 461 | 22.947 | 54.111 | 53.658 | 1.00 | 18.05 | D | N |
| ATOM | 2779 | C | ARG | D | 461 | 27.884 | 50.793 | 50.064 | 1.00 | 18.93 | D | C |
| ATOM | 2780 | O | ARG | D | 461 | 26.782 | 50.707 | 49.522 | 1.00 | 21.28 | D | O |
| ATOM | 2781 | N | ILE | D | 462 | 29.011 | 50.522 | 49.418 | 1.00 | 19.32 | D | N |
| ATOM | 2782 | CA | ILE | D | 462 | 28.980 | 50.142 | 48.017 | 1.00 | 19.86 | D | C |
| ATOM | 2783 | CB | ILE | D | 462 | 29.556 | 51.282 | 47.117 | 1.00 | 20.02 | D | C |
| ATOM | 2784 | CG2 | ILE | D | 462 | 28.777 | 52.565 | 47.358 | 1.00 | 17.52 | D | C |
| ATOM | 2785 | CG1 | ILE | D | 462 | 31.048 | 51.504 | 47.412 | 1.00 | 18.15 | D | C |
| ATOM | 2786 | CD1 | ILE | D | 462 | 31.665 | 52.675 | 46.676 | 1.00 | 15.17 | D | C |
| ATOM | 2787 | C | ILE | D | 462 | 29.730 | 48.857 | 47.730 | 1.00 | 19.78 | D | C |
| ATOM | 2788 | O | ILE | D | 462 | 30.449 | 48.770 | 46.741 | 1.00 | 19.68 | D | O |
| ATOM | 2789 | N | TYR | D | 463 | 29.558 | 47.863 | 48.594 | 1.00 | 18.49 | D | N |
| ATOM | 2790 | CA | TYR | D | 463 | 30.221 | 46.588 | 48.394 | 1.00 | 18.39 | D | C |
| ATOM | 2791 | CB | TYR | D | 463 | 29.834 | 45.605 | 49.506 | 1.00 | 17.14 | D | C |
| ATOM | 2792 | CG | TYR | D | 463 | 29.885 | 44.151 | 49.084 | 1.00 | 14.29 | D | C |
| ATOM | 2793 | CD1 | TYR | D | 463 | 31.074 | 43.424 | 49.164 | 1.00 | 15.10 | D | C |
| ATOM | 2794 | CE1 | TYR | D | 463 | 31.135 | 42.092 | 48.742 | 1.00 | 14.03 | D | C |
| ATOM | 2795 | CD2 | TYR | D | 463 | 28.747 | 43.512 | 48.575 | 1.00 | 12.71 | D | C |
| ATOM | 2796 | CE2 | TYR | D | 463 | 28.795 | 42.180 | 48.150 | 1.00 | 14.62 | D | C |
| ATOM | 2797 | CZ | TYR | D | 463 | 29.992 | 41.477 | 48.235 | 1.00 | 16.00 | D | C |
| ATOM | 2798 | OH | TYR | D | 463 | 30.051 | 40.166 | 47.801 | 1.00 | 18.71 | D | O |
| ATOM | 2799 | C | TYR | D | 463 | 29.812 | 46.007 | 47.040 | 1.00 | 20.29 | D | C |
| ATOM | 2800 | O | TYR | D | 463 | 30.625 | 45.400 | 46.344 | 1.00 | 19.55 | D | O |
| ATOM | 2801 | N | ASP | D | 464 | 28.544 | 46.189 | 46.675 | 1.00 | 21.92 | D | N |
| ATOM | 2802 | CA | ASP | D | 464 | 28.034 | 45.646 | 45.421 | 1.00 | 22.39 | D | C |
| ATOM | 2803 | CB | ASP | D | 464 | 26.532 | 45.916 | 45.275 | 1.00 | 20.18 | D | C |
| ATOM | 2804 | CG | ASP | D | 464 | 26.163 | 47.368 | 45.524 | 1.00 | 26.23 | D | C |
| ATOM | 2805 | OD1 | ASP | D | 464 | 25.059 | 47.767 | 45.111 | 1.00 | 32.85 | D | O |
| ATOM | 2806 | OD2 | ASP | D | 464 | 26.951 | 48.119 | 46.132 | 1.00 | 26.48 | D | O |
| ATOM | 2807 | C | ASP | D | 464 | 28.799 | 46.200 | 44.232 | 1.00 | 22.27 | D | C |
| ATOM | 2808 | O | ASP | D | 464 | 29.092 | 45.475 | 43.293 | 1.00 | 24.15 | D | O |
| ATOM | 2809 | N | VAL | D | 465 | 29.144 | 47.477 | 44.286 | 1.00 | 21.69 | D | N |
| ATOM | 2810 | CA | VAL | D | 465 | 29.892 | 48.095 | 43.209 | 1.00 | 22.03 | D | C |
| ATOM | 2811 | CB | VAL | D | 465 | 30.092 | 49.596 | 43.486 | 1.00 | 21.75 | D | C |
| ATOM | 2812 | CG1 | VAL | D | 465 | 31.003 | 50.211 | 42.454 | 1.00 | 22.93 | D | C |
| ATOM | 2813 | CG2 | VAL | D | 465 | 28.759 | 50.300 | 43.469 | 1.00 | 19.46 | D | C |
| ATOM | 2814 | C | VAL | D | 465 | 31.254 | 47.405 | 43.061 | 1.00 | 26.24 | D | C |
| ATOM | 2815 | O | VAL | D | 465 | 31.635 | 46.991 | 41.960 | 1.00 | 25.35 | D | O |
| ATOM | 2816 | N | PHE | D | 466 | 31.983 | 47.282 | 44.170 | 1.00 | 26.09 | D | N |
| ATOM | 2817 | CA | PHE | D | 466 | 33.297 | 46.640 | 44.166 | 1.00 | 25.80 | D | C |
| ATOM | 2818 | CB | PHE | D | 466 | 33.983 | 46.808 | 45.521 | 1.00 | 25.60 | D | C |
| ATOM | 2819 | CG | PHE | D | 466 | 34.279 | 48.230 | 45.875 | 1.00 | 27.47 | D | C |
| ATOM | 2820 | CD1 | PHE | D | 466 | 34.617 | 49.150 | 44.890 | 1.00 | 28.72 | D | C |
| ATOM | 2821 | CD2 | PHE | D | 466 | 34.208 | 48.660 | 47.195 | 1.00 | 30.91 | D | C |
| ATOM | 2822 | CE1 | PHE | D | 466 | 34.883 | 50.487 | 45.211 | 1.00 | 29.02 | D | C |
| ATOM | 2823 | CE2 | PHE | D | 466 | 34.472 | 49.991 | 47.528 | 1.00 | 30.68 | D | C |
| ATOM | 2824 | CZ | PHE | D | 466 | 34.808 | 50.906 | 46.533 | 1.00 | 30.53 | D | C |
| ATOM | 2825 | C | PHE | D | 466 | 33.211 | 45.157 | 43.848 | 1.00 | 25.78 | D | C |
| ATOM | 2826 | O | PHE | D | 466 | 34.102 | 44.617 | 43.207 | 1.00 | 27.65 | D | O |
| ATOM | 2827 | N | ARG | D | 467 | 32.150 | 44.501 | 44.308 | 1.00 | 24.82 | D | N |
| ATOM | 2828 | CA | ARG | D | 467 | 31.973 | 43.079 | 44.062 | 1.00 | 24.98 | D | C |
| ATOM | 2829 | CB | ARG | D | 467 | 30.767 | 42.547 | 44.840 | 1.00 | 25.55 | D | C |
| ATOM | 2830 | CG | ARG | D | 467 | 30.457 | 41.078 | 44.584 | 1.00 | 25.43 | D | C |
| ATOM | 2831 | CD | ARG | D | 467 | 31.695 | 40.220 | 44.786 | 1.00 | 30.68 | D | C |
| ATOM | 2832 | NE | ARG | D | 467 | 31.411 | 38.800 | 44.599 | 1.00 | 36.26 | D | N |
| ATOM | 2833 | CZ | ARG | D | 467 | 31.058 | 38.249 | 43.439 | 1.00 | 39.41 | D | C |
| ATOM | 2834 | NH1 | ARG | D | 467 | 30.944 | 38.999 | 42.351 | 1.00 | 40.17 | D | N |
| ATOM | 2835 | NH2 | ARG | D | 467 | 30.813 | 36.945 | 43.360 | 1.00 | 41.32 | D | N |
| ATOM | 2836 | C | ARG | D | 467 | 31.770 | 42.798 | 42.578 | 1.00 | 26.50 | D | C |
| ATOM | 2837 | O | ARG | D | 467 | 32.397 | 41.902 | 42.017 | 1.00 | 25.17 | D | O |
| ATOM | 2838 | N | SER | D | 468 | 30.899 | 43.572 | 41.944 | 1.00 | 25.45 | D | N |
| ATOM | 2839 | CA | SER | D | 468 | 30.602 | 43.374 | 40.539 | 1.00 | 27.67 | D | C |
| ATOM | 2840 | CB | SER | D | 468 | 29.396 | 44.213 | 40.138 | 1.00 | 26.95 | D | C |
| ATOM | 2841 | OG | SER | D | 468 | 29.688 | 45.584 | 40.279 | 1.00 | 36.11 | D | O |
| ATOM | 2842 | C | SER | D | 468 | 31.799 | 43.692 | 39.656 | 1.00 | 28.51 | D | C |
| ATOM | 2843 | O | SER | D | 468 | 31.889 | 43.211 | 38.528 | 1.00 | 30.09 | D | O |
| ATOM | 2844 | N | LYS | D | 469 | 32.718 | 44.499 | 40.175 | 1.00 | 27.90 | D | N |
| ATOM | 2845 | CA | LYS | D | 469 | 33.952 | 44.855 | 39.468 | 1.00 | 26.23 | D | C |
| ATOM | 2846 | CB | LYS | D | 469 | 34.421 | 46.240 | 39.883 | 1.00 | 27.42 | D | C |
| ATOM | 2847 | CG | LYS | D | 469 | 33.975 | 47.361 | 38.996 | 1.00 | 34.06 | D | C |
| ATOM | 2848 | CD | LYS | D | 469 | 34.577 | 48.673 | 39.485 | 1.00 | 37.92 | D | C |
| ATOM | 2849 | CE | LYS | D | 469 | 33.812 | 49.879 | 38.945 | 1.00 | 42.49 | D | C |
| ATOM | 2850 | NZ | LYS | D | 469 | 32.320 | 49.723 | 39.037 | 1.00 | 45.55 | D | N |
| ATOM | 2851 | C | LYS | D | 469 | 35.039 | 43.858 | 39.886 | 1.00 | 26.89 | D | C |
| ATOM | 2852 | O | LYS | D | 469 | 36.206 | 43.994 | 39.510 | 1.00 | 24.63 | D | O |
| ATOM | 2853 | N | ASN | D | 470 | 34.650 | 42.877 | 40.697 | 1.00 | 25.94 | D | N |
| ATOM | 2854 | CA | ASN | D | 470 | 35.578 | 41.869 | 41.185 | 1.00 | 28.86 | D | C |
| ATOM | 2855 | CB | ASN | D | 470 | 36.044 | 40.976 | 40.037 | 1.00 | 31.47 | D | C |
| ATOM | 2856 | CG | ASN | D | 470 | 34.895 | 40.309 | 39.341 | 1.00 | 32.89 | D | C |
| ATOM | 2857 | OD1 | ASN | D | 470 | 34.155 | 39.536 | 39.951 | 1.00 | 33.24 | D | O |
| ATOM | 2858 | ND2 | ASN | D | 470 | 34.721 | 40.613 | 38.058 | 1.00 | 33.69 | D | N |
| ATOM | 2859 | C | ASN | D | 470 | 36.774 | 42.481 | 41.896 | 1.00 | 29.17 | D | C |
| ATOM | 2860 | O | ASN | D | 470 | 37.908 | 42.023 | 41.752 | 1.00 | 27.94 | D | O |
| ATOM | 2861 | N | PHE | D | 471 | 36.510 | 43.537 | 42.657 | 1.00 | 29.58 | D | N |
| ATOM | 2862 | CA | PHE | D | 471 | 37.543 | 44.185 | 43.442 | 1.00 | 28.72 | D | C |
| ATOM | 2863 | CB | PHE | D | 471 | 37.204 | 45.651 | 43.671 | 1.00 | 29.79 | D | C |
| ATOM | 2864 | CG | PHE | D | 471 | 37.668 | 46.565 | 42.575 | 1.00 | 32.72 | D | C |
| ATOM | 2865 | CD1 | PHE | D | 471 | 38.414 | 46.084 | 41.504 | 1.00 | 34.05 | D | C |
| ATOM | 2866 | CD2 | PHE | D | 471 | 37.356 | 47.915 | 42.613 | 1.00 | 34.65 | D | C |
| ATOM | 2867 | CE1 | PHE | D | 471 | 38.839 | 46.935 | 40.487 | 1.00 | 33.84 | D | C |
| ATOM | 2868 | CE2 | PHE | D | 471 | 37.777 | 48.774 | 41.601 | 1.00 | 36.39 | D | C |
| ATOM | 2869 | CZ | PHE | D | 471 | 38.520 | 48.281 | 40.537 | 1.00 | 35.17 | D | C |
| ATOM | 2870 | C | PHE | D | 471 | 37.386 | 43.457 | 44.786 | 1.00 | 29.40 | D | C |
| ATOM | 2871 | O | PHE | D | 471 | 38.568 | 43.569 | 45.521 | 1.00 | 30.61 | D | O |
| ATOM | 2872 | N | LEU | D | 472 | 36.519 | 42.709 | 45.087 | 1.00 | 26.25 | D | N |
| ATOM | 2873 | CA | LEU | D | 472 | 36.391 | 41.942 | 46.329 | 1.00 | 26.69 | D | C |
| ATOM | 2874 | CB | LEU | D | 472 | 35.618 | 42.740 | 47.399 | 1.00 | 26.87 | D | C |
| ATOM | 2875 | CG | LEU | D | 472 | 36.042 | 44.172 | 47.747 | 1.00 | 27.21 | D | C |
| ATOM | 2876 | CD1 | LEU | D | 472 | 34.904 | 44.876 | 48.449 | 1.00 | 26.64 | D | C |
| ATOM | 2877 | CD2 | LEU | D | 472 | 37.283 | 44.161 | 48.632 | 1.00 | 24.11 | D | C |
| ATOM | 2878 | C | LEU | D | 472 | 35.635 | 40.644 | 46.086 | 1.00 | 25.59 | D | C |
| ATOM | 2879 | O | LEU | D | 472 | 34.760 | 40.588 | 45.224 | 1.00 | 26.21 | D | O |
| ATOM | 2880 | N | PRO | D | 473 | 35.950 | 39.586 | 46.862 | 1.00 | 25.52 | D | N |
| ATOM | 2881 | CD | PRO | D | 473 | 37.020 | 39.590 | 47.877 | 1.00 | 24.25 | D | C |
| ATOM | 2882 | CA | PRO | D | 473 | 35.311 | 38.268 | 46.754 | 1.00 | 23.30 | D | C |
| ATOM | 2883 | CB | PRO | D | 473 | 36.395 | 37.314 | 47.239 | 1.00 | 23.57 | D | C |
| ATOM | 2884 | CG | PRO | D | 473 | 37.163 | 38.124 | 48.254 | 1.00 | 23.97 | D | C |
| ATOM | 2885 | C | PRO | D | 473 | 34.033 | 38.123 | 47.576 | 1.00 | 25.29 | D | C |
| ATOM | 2886 | O | PRO | D | 473 | 33.138 | 37.339 | 47.224 | 1.00 | 24.27 | D | O |
| ATOM | 2887 | N | HIS | D | 474 | 33.956 | 38.876 | 48.677 | 1.00 | 24.18 | D | N |
| ATOM | 2888 | CA | HIS | D | 474 | 32.805 | 38.811 | 49.592 | 1.00 | 21.49 | D | C |
| ATOM | 2889 | CB | HIS | D | 474 | 32.852 | 37.500 | 50.403 | 1.00 | 17.77 | D | C |
| ATOM | 2890 | CG | HIS | D | 474 | 34.156 | 37.276 | 51.103 | 1.00 | 20.63 | D | C |
| ATOM | 2891 | CD2 | HIS | D | 474 | 34.808 | 38.013 | 52.034 | 1.00 | 21.46 | D | C |
| ATOM | 2892 | ND1 | HIS | D | 474 | 34.989 | 36.221 | 50.800 | 1.00 | 22.45 | D | N |
| ATOM | 2893 | CE1 | HIS | D | 474 | 36.099 | 36.320 | 51.512 | 1.00 | 22.11 | D | C |
| ATOM | 2894 | NE2 | HIS | D | 474 | 36.015 | 37.399 | 52.268 | 1.00 | 21.79 | D | N |
| ATOM | 2895 | C | HIS | D | 474 | 32.813 | 40.015 | 50.546 | 1.00 | 22.36 | D | C |
| ATOM | 2896 | O | HIS | D | 474 | 33.740 | 40.832 | 50.523 | 1.00 | 18.53 | D | O |
| ATOM | 2897 | N | PHE | D | 475 | 31.797 | 40.112 | 51.403 | 1.00 | 23.17 | D | N |
| ATOM | 2898 | CA | PHE | D | 475 | 31.711 | 41.245 | 52.328 | 1.00 | 21.90 | D | C |
| ATOM | 2899 | CB | PHE | D | 475 | 30.323 | 41.311 | 52.966 | 1.00 | 20.86 | D | C |
| ATOM | 2900 | CG | PHE | D | 475 | 30.035 | 42.623 | 53.624 | 1.00 | 20.30 | D | C |
| ATOM | 2901 | CD1 | PHE | D | 475 | 29.874 | 42.702 | 54.997 | 1.00 | 20.21 | D | C |
| ATOM | 2902 | CD2 | PHE | D | 475 | 29.944 | 43.791 | 52.867 | 1.00 | 18.37 | D | C |
| ATOM | 2903 | CE1 | PHE | D | 475 | 29.624 | 43.935 | 55.615 | 1.00 | 19.79 | D | C |
| ATOM | 2904 | CE2 | PHE | D | 475 | 29.696 | 45.025 | 53.471 | 1.00 | 19.63 | D | C |
| ATOM | 2905 | CZ | PHE | D | 475 | 29.535 | 45.096 | 54.854 | 1.00 | 17.95 | D | C |
| ATOM | 2906 | C | PHE | D | 475 | 32.775 | 41.252 | 53.419 | 1.00 | 20.38 | D | C |
| ATOM | 2907 | O | PHE | D | 475 | 33.191 | 42.317 | 53.877 | 1.00 | 19.90 | D | O |
| ATOM | 2908 | N | GLY | D | 476 | 33.212 | 40.061 | 53.826 | 1.00 | 20.23 | D | N |
| ATOM | 2909 | CA | GLY | D | 476 | 34.226 | 39.951 | 54.858 | 1.00 | 17.16 | D | C |
| ATOM | 2910 | C | GLY | D | 476 | 35.511 | 40.654 | 54.476 | 1.00 | 18.90 | D | C |
| ATOM | 2911 | O | GLY | D | 476 | 36.188 | 41.251 | 55.323 | 1.00 | 18.85 | D | O |
| ATOM | 2912 | N | LYS | D | 477 | 35.861 | 40.596 | 53.195 | 1.00 | 18.96 | D | N |
| ATOM | 2913 | CA | LYS | D | 477 | 37.087 | 41.239 | 52.743 | 1.00 | 16.90 | D | C |
| ATOM | 2914 | CB | LYS | D | 477 | 37.440 | 40.766 | 51.339 | 1.00 | 18.20 | D | C |
| ATOM | 2915 | CG | LYS | D | 477 | 38.745 | 41.326 | 50.825 | 1.00 | 19.93 | D | C |
| ATOM | 2916 | CD | LYS | D | 477 | 39.945 | 40.690 | 51.508 | 1.00 | 23.55 | D | C |
| ATOM | 2917 | CE | LYS | D | 477 | 41.190 | 41.553 | 51.283 | 1.00 | 26.87 | D | C |
| ATOM | 2918 | NZ | LYS | D | 477 | 42.440 | 40.884 | 51.720 | 1.00 | 29.81 | D | N |
| ATOM | 2919 | C | LYS | D | 477 | 36.977 | 42.765 | 52.789 | 1.00 | 16.89 | D | C |
| ATOM | 2920 | O | LYS | D | 477 | 37.980 | 43.463 | 52.973 | 1.00 | 15.94 | D | O |
| ATOM | 2921 | N | MET | D | 478 | 35.765 | 43.293 | 52.622 | 1.00 | 16.72 | D | N |
| ATOM | 2922 | CA | MET | D | 478 | 35.592 | 44.742 | 52.695 | 1.00 | 17.24 | D | C |
| ATOM | 2923 | CB | MET | D | 478 | 34.192 | 45.153 | 52.257 | 1.00 | 17.23 | D | C |
| ATOM | 2924 | CG | MET | D | 478 | 34.059 | 46.667 | 52.117 | 1.00 | 17.25 | D | C |
| ATOM | 2925 | SD | MET | D | 478 | 32.412 | 47.203 | 51.563 | 1.00 | 19.52 | D | S |
| ATOM | 2926 | CE | MET | D | 478 | 32.548 | 48.970 | 51.711 | 1.00 | 18.10 | D | C |
| ATOM | 2927 | C | MET | D | 478 | 35.810 | 45.199 | 54.144 | 1.00 | 17.57 | D | C |
| ATOM | 2928 | O | MET | D | 478 | 36.497 | 46.198 | 54.405 | 1.00 | 15.20 | D | O |
| ATOM | 2929 | N | LEU | D | 479 | 35.217 | 44.445 | 55.075 | 1.00 | 16.48 | D | N |
| ATOM | 2930 | CA | LEU | D | 479 | 35.326 | 44.738 | 56.500 | 1.00 | 15.60 | D | C |
| ATOM | 2931 | CB | LEU | D | 479 | 34.478 | 43.751 | 57.313 | 1.00 | 13.16 | D | C |
| ATOM | 2932 | CG | LEU | D | 479 | 32.953 | 43.952 | 57.290 | 1.00 | 11.03 | D | C |
| ATOM | 2933 | CD1 | LEU | D | 479 | 32.281 | 42.835 | 58.077 | 1.00 | 8.61 | D | C |
| ATOM | 2934 | CD2 | LEU | D | 479 | 32.589 | 45.289 | 57.880 | 1.00 | 7.22 | D | C |
| ATOM | 2935 | C | LEU | D | 479 | 36.784 | 44.645 | 56.899 | 1.00 | 15.13 | D | C |
| ATOM | 2936 | O | LEU | D | 479 | 37.278 | 45.466 | 57.679 | 1.00 | 15.57 | D | O |
| ATOM | 2937 | N | GLU | D | 480 | 37.484 | 43.658 | 56.346 | 1.00 | 16.46 | D | N |
| ATOM | 2938 | CA | GLU | D | 480 | 38.900 | 43.497 | 56.644 | 1.00 | 16.21 | D | C |
| ATOM | 2939 | CB | GLU | D | 480 | 39.432 | 42.182 | 56.060 | 1.00 | 15.16 | D | C |
| ATOM | 2940 | CG | GLU | D | 480 | 40.925 | 42.002 | 56.276 | 1.00 | 21.30 | D | C |
| ATOM | 2941 | CD | GLU | D | 480 | 41.416 | 40.601 | 55.976 | 1.00 | 26.60 | D | C |
| ATOM | 2942 | OE1 | GLU | D | 480 | 40.610 | 39.755 | 55.534 | 1.00 | 32.64 | D | O |
| ATOM | 2943 | OE2 | GLU | D | 480 | 42.618 | 40.340 | 56.182 | 1.00 | 31.20 | D | O |
| ATOM | 2944 | C | GLU | D | 480 | 39.743 | 44.680 | 56.135 | 1.00 | 15.90 | D | C |
| ATOM | 2945 | O | GLU | D | 480 | 40.656 | 45.128 | 56.825 | 1.00 | 16.71 | D | O |
| ATOM | 2946 | N | ASN | D | 481 | 39.435 | 45.202 | 54.947 | 1.00 | 17.50 | D | N |
| ATOM | 2947 | CA | ASN | D | 481 | 40.199 | 46.325 | 54.400 | 1.00 | 17.75 | D | C |
| ATOM | 2948 | CB | ASN | D | 481 | 39.828 | 46.578 | 52.940 | 1.00 | 18.60 | D | C |
| ATOM | 2949 | CG | ASN | D | 481 | 40.256 | 45.442 | 52.022 | 1.00 | 23.81 | D | C |
| ATOM | 2950 | OD1 | ASN | D | 481 | 39.691 | 45.262 | 50.936 | 1.00 | 23.78 | D | O |
| ATOM | 2951 | ND2 | ASN | D | 481 | 41.255 | 44.676 | 52.447 | 1.00 | 18.58 | D | N |
| ATOM | 2952 | C | ASN | D | 481 | 39.949 | 47.593 | 55.197 | 1.00 | 17.38 | D | C |
| ATOM | 2953 | O | ASN | D | 481 | 40.842 | 48.429 | 55.356 | 1.00 | 14.56 | D | O |
| ATOM | 2954 | N | VAL | D | 482 | 38.723 | 47.731 | 55.700 | 1.00 | 17.32 | D | N |
| ATOM | 2955 | CA | VAL | D | 482 | 38.357 | 48.910 | 56.485 | 1.00 | 16.40 | D | C |
| ATOM | 2956 | CB | VAL | D | 482 | 36.815 | 49.038 | 56.647 | 1.00 | 13.83 | D | C |
| ATOM | 2957 | CG1 | VAL | D | 482 | 36.483 | 50.265 | 57.507 | 1.00 | 12.25 | D | C |
| ATOM | 2958 | CG2 | VAL | D | 482 | 36.145 | 49.166 | 55.285 | 1.00 | 12.82 | D | C |
| ATOM | 2959 | C | VAL | D | 482 | 38.960 | 48.925 | 57.893 | 1.00 | 16.00 | D | C |
| ATOM | 2960 | O | VAL | D | 482 | 39.502 | 49.945 | 58.333 | 1.00 | 16.03 | D | O |
| ATOM | 2961 | N | PHE | D | 483 | 38.885 | 47.790 | 58.587 | 1.00 | 15.82 | D | N |
| ATOM | 2962 | CA | PHE | D | 483 | 39.356 | 47.722 | 59.970 | 1.00 | 15.88 | D | C |
| ATOM | 2963 | CB | PHE | D | 483 | 38.282 | 47.027 | 60.815 | 1.00 | 14.96 | D | C |
| ATOM | 2964 | CG | PHE | D | 483 | 36.992 | 47.792 | 60.894 | 1.00 | 12.95 | D | C |
| ATOM | 2965 | CD1 | PHE | D | 483 | 36.944 | 49.006 | 61.554 | 1.00 | 10.45 | D | C |
| ATOM | 2966 | CD2 | PHE | D | 483 | 35.834 | 47.307 | 60.279 | 1.00 | 11.18 | D | C |
| ATOM | 2967 | CE1 | PHE | D | 483 | 35.762 | 49.745 | 61.607 | 1.00 | 11.71 | D | C |
| ATOM | 2968 | CE2 | PHE | D | 483 | 34.647 | 48.034 | 60.324 | 1.00 | 10.67 | D | C |
| ATOM | 2969 | CZ | PHE | D | 483 | 34.614 | 49.261 | 60.993 | 1.00 | 11.50 | D | C |
| ATOM | 2970 | C | PHE | D | 483 | 40.719 | 47.132 | 60.325 | 1.00 | 14.80 | D | C |
| ATOM | 2971 | O | PHE | D | 483 | 41.378 | 47.642 | 61.221 | 1.00 | 16.27 | D | O |
| ATOM | 2972 | N | MET | D | 484 | 41.149 | 46.079 | 59.640 | 1.00 | 17.62 | D | N |
| ATOM | 2973 | CA | MET | D | 484 | 42.426 | 45.434 | 59.965 | 1.00 | 20.81 | D | C |
| ATOM | 2974 | CB | MET | D | 484 | 42.706 | 44.292 | 58.981 | 1.00 | 24.22 | D | C |
| ATOM | 2975 | CG | MET | D | 484 | 43.882 | 43.397 | 59.378 | 1.00 | 26.74 | D | C |
| ATOM | 2976 | SD | MET | D | 484 | 43.587 | 42.384 | 60.858 | 1.00 | 25.88 | D | S |
| ATOM | 2977 | CE | MET | D | 484 | 42.549 | 41.109 | 60.206 | 1.00 | 24.47 | D | C |
| ATOM | 2978 | C | MET | D | 484 | 43.644 | 46.347 | 60.034 | 1.00 | 20.88 | D | C |
| ATOM | 2979 | O | MET | D | 484 | 44.437 | 46.257 | 60.966 | 1.00 | 23.73 | D | O |
| ATOM | 2980 | N | PRO | D | 485 | 43.824 | 47.228 | 59.043 | 1.00 | 21.67 | D | N |
| ATOM | 2981 | CD | PRO | D | 485 | 43.025 | 47.470 | 57.826 | 1.00 | 20.81 | D | C |
| ATOM | 2982 | CA | PRO | D | 485 | 44.994 | 48.102 | 59.112 | 1.00 | 18.91 | D | C |
| ATOM | 2983 | CB | PRO | D | 485 | 44.905 | 48.926 | 57.825 | 1.00 | 19.19 | D | C |
| ATOM | 2984 | CG | PRO | D | 485 | 44.013 | 48.119 | 56.906 | 1.00 | 19.37 | D | C |
| ATOM | 2985 | C | PRO | D | 485 | 44.987 | 48.978 | 60.357 | 1.00 | 21.09 | D | C |
| ATOM | 2986 | O | PRO | D | 485 | 46.049 | 49.295 | 60.906 | 1.00 | 20.59 | D | O |
| ATOM | 2987 | N | VAL | D | 486 | 43.789 | 49.360 | 60.801 | 1.00 | 19.94 | D | N |
| ATOM | 2988 | CA | VAL | D | 486 | 43.644 | 50.218 | 61.971 | 1.00 | 20.41 | D | C |
| ATOM | 2989 | CB | VAL | D | 486 | 42.227 | 50.820 | 62.030 | 1.00 | 22.37 | D | C |
| ATOM | 2990 | CG1 | VAL | D | 486 | 42.071 | 51.675 | 63.264 | 1.00 | 22.30 | D | C |
| ATOM | 2991 | CG2 | VAL | D | 486 | 41.996 | 51.670 | 60.806 | 1.00 | 20.29 | D | C |
| ATOM | 2992 | C | VAL | D | 486 | 43.956 | 49.435 | 63.245 | 1.00 | 19.90 | D | C |
| ATOM | 2993 | O | VAL | D | 486 | 44.550 | 49.970 | 64.182 | 1.00 | 21.12 | D | O |
| ATOM | 2994 | N | PHE | D | 487 | 43.557 | 48.168 | 63.278 | 1.00 | 19.85 | D | N |
| ATOM | 2995 | CA | PHE | D | 487 | 43.855 | 47.305 | 64.418 | 1.00 | 20.72 | D | C |
| ATOM | 2996 | CB | PHE | D | 487 | 43.139 | 45.965 | 64.284 | 1.00 | 19.47 | D | C |
| ATOM | 2997 | CG | PHE | D | 487 | 41.774 | 45.934 | 64.918 | 1.00 | 21.16 | D | C |
| ATOM | 2998 | CD1 | PHE | D | 487 | 40.644 | 46.297 | 64.187 | 1.00 | 19.13 | D | C |
| ATOM | 2999 | CD2 | PHE | D | 487 | 41.615 | 45.537 | 66.244 | 1.00 | 18.71 | D | C |
| ATOM | 3000 | CE1 | PHE | D | 487 | 39.372 | 46.266 | 64.770 | 1.00 | 19.86 | D | C |
| ATOM | 3001 | CE2 | PHE | D | 487 | 40.347 | 45.502 | 66.838 | 1.00 | 18.24 | D | C |
| ATOM | 3002 | CZ | PHE | D | 487 | 39.225 | 45.866 | 66.103 | 1.00 | 17.53 | D | C |
| ATOM | 3003 | C | PHE | D | 487 | 45.366 | 47.052 | 64.439 | 1.00 | 24.49 | D | C |
| ATOM | 3004 | O | PHE | D | 487 | 45.980 | 46.977 | 65.503 | 1.00 | 25.52 | D | O |
| ATOM | 3005 | N | GLU | D | 488 | 45.963 | 46.916 | 63.253 | 1.00 | 24.57 | D | N |
| ATOM | 3006 | CA | GLU | D | 488 | 47.402 | 46.678 | 63.140 | 1.00 | 23.86 | D | C |
| ATOM | 3007 | CB | GLU | D | 488 | 47.786 | 46.416 | 61.690 | 1.00 | 26.76 | D | C |
| ATOM | 3008 | CG | GLU | D | 488 | 48.065 | 44.975 | 61.399 | 1.00 | 33.65 | D | C |
| ATOM | 3009 | CD | GLU | D | 488 | 47.805 | 44.636 | 59.949 | 1.00 | 40.04 | D | C |
| ATOM | 3010 | OE1 | GLU | D | 488 | 47.935 | 45.557 | 59.102 | 1.00 | 38.42 | D | O |
| ATOM | 3011 | OE2 | GLU | D | 488 | 47.474 | 43.454 | 59.661 | 1.00 | 42.95 | D | O |
| ATOM | 3012 | C | GLU | D | 488 | 48.222 | 47.848 | 63.654 | 1.00 | 23.44 | D | C |
| ATOM | 3013 | O | GLU | D | 488 | 49.257 | 47.651 | 64.289 | 1.00 | 21.64 | D | O |
| ATOM | 3014 | N | ALA | D | 489 | 47.774 | 49.065 | 63.360 | 1.00 | 19.57 | D | N |
| ATOM | 3015 | CA | ALA | D | 489 | 48.490 | 50.245 | 63.813 | 1.00 | 21.79 | D | C |
| ATOM | 3016 | CB | ALA | D | 489 | 47.962 | 51.504 | 63.090 | 1.00 | 18.51 | D | C |
| ATOM | 3017 | C | ALA | D | 489 | 48.334 | 50.391 | 65.332 | 1.00 | 22.00 | D | C |
| ATOM | 3018 | O | ALA | D | 489 | 49.206 | 50.934 | 65.996 | 1.00 | 22.33 | D | O |
| ATOM | 3019 | N | THR | D | 490 | 47.222 | 49.896 | 65.870 | 1.00 | 22.47 | D | N |
| ATOM | 3020 | CA | THR | D | 490 | 46.948 | 49.982 | 67.301 | 1.00 | 24.55 | D | C |
| ATOM | 3021 | CB | THR | D | 490 | 45.483 | 49.611 | 67.588 | 1.00 | 22.90 | D | C |
| ATOM | 3022 | OG1 | THR | D | 490 | 44.624 | 50.614 | 67.019 | 1.00 | 23.87 | D | O |
| ATOM | 3023 | CG2 | THR | D | 490 | 45.241 | 49.518 | 69.091 | 1.00 | 21.52 | D | C |
| ATOM | 3024 | C | THR | D | 490 | 47.870 | 49.057 | 68.102 | 1.00 | 25.88 | D | C |
| ATOM | 3025 | O | THR | D | 490 | 48.462 | 49.440 | 69.118 | 1.00 | 26.05 | D | O |
| ATOM | 3026 | N | ILE | D | 491 | 47.982 | 47.834 | 67.616 | 1.00 | 24.61 | D | N |
| ATOM | 3027 | CA | ILE | D | 491 | 48.807 | 46.817 | 68.220 | 1.00 | 24.62 | D | C |
| ATOM | 3028 | CB | ILE | D | 491 | 48.407 | 45.461 | 67.607 | 1.00 | 25.05 | D | C |
| ATOM | 3029 | CG2 | ILE | D | 491 | 49.551 | 44.802 | 66.894 | 1.00 | 30.60 | D | C |
| ATOM | 3030 | CG1 | ILE | D | 491 | 47.849 | 44.583 | 68.699 | 1.00 | 29.80 | D | C |
| ATOM | 3031 | CD1 | ILE | D | 491 | 46.358 | 44.573 | 68.705 | 1.00 | 28.90 | D | C |
| ATOM | 3032 | C | ILE | D | 491 | 50.302 | 47.133 | 68.044 | 1.00 | 25.11 | D | C |
| ATOM | 3033 | O | ILE | D | 491 | 51.096 | 46.935 | 68.956 | 1.00 | 26.04 | D | O |
| ATOM | 3034 | N | ASN | D | 492 | 50.676 | 47.657 | 66.881 | 1.00 | 25.43 | D | N |
| ATOM | 3035 | CA | ASN | D | 492 | 52.066 | 47.991 | 66.599 | 1.00 | 24.48 | D | C |
| ATOM | 3036 | CB | ASN | D | 492 | 52.634 | 47.011 | 65.579 | 1.00 | 24.89 | D | C |
| ATOM | 3037 | CG | ASN | D | 492 | 52.532 | 45.585 | 66.047 | 1.00 | 27.12 | D | C |
| ATOM | 3038 | OD1 | ASN | D | 492 | 52.920 | 45.266 | 67.174 | 1.00 | 27.97 | D | O |
| ATOM | 3039 | ND2 | ASN | D | 492 | 51.999 | 44.712 | 65.195 | 1.00 | 24.14 | D | N |
| ATOM | 3040 | C | ASN | D | 492 | 52.205 | 49.402 | 66.058 | 1.00 | 24.27 | D | C |
| ATOM | 3041 | O | ASN | D | 492 | 52.485 | 49.594 | 64.877 | 1.00 | 27.14 | D | O |
| ATOM | 3042 | N | PRO | D | 493 | 52.053 | 50.410 | 66.926 | 1.00 | 23.74 | D | N |
| ATOM | 3043 | CD | PRO | D | 493 | 51.788 | 50.287 | 68.368 | 1.00 | 22.64 | D | C |
| ATOM | 3044 | CA | PRO | D | 493 | 52.161 | 51.811 | 66.504 | 1.00 | 24.66 | D | C |
| ATOM | 3045 | CB | PRO | D | 493 | 51.883 | 52.601 | 67.784 | 1.00 | 21.11 | D | C |
| ATOM | 3046 | CG | PRO | D | 493 | 51.227 | 51.614 | 68.718 | 1.00 | 20.03 | D | C |
| ATOM | 3047 | C | PRO | D | 493 | 53.505 | 52.186 | 65.890 | 1.00 | 26.30 | D | C |
| ATOM | 3048 | O | PRO | D | 493 | 53.581 | 53.026 | 64.991 | 1.00 | 26.78 | D | O |
| ATOM | 3049 | N | GLN | D | 494 | 54.566 | 51.571 | 66.387 | 1.00 | 26.41 | D | N |
| ATOM | 3050 | CA | GLN | D | 494 | 55.897 | 51.866 | 65.894 | 1.00 | 28.94 | D | C |
| ATOM | 3051 | CB | GLN | D | 494 | 56.922 | 51.251 | 66.828 | 1.00 | 33.45 | D | C |
| ATOM | 3052 | CG | GLN | D | 494 | 56.703 | 51.642 | 68.270 | 1.00 | 37.23 | D | C |
| ATOM | 3053 | CD | GLN | D | 494 | 57.349 | 52.959 | 68.600 | 1.00 | 39.68 | D | C |
| ATOM | 3054 | OE1 | GLN | D | 494 | 58.018 | 53.087 | 69.620 | 1.00 | 47.18 | D | O |
| ATOM | 3055 | NE2 | GLN | D | 494 | 57.160 | 53.949 | 67.737 | 1.00 | 41.96 | D | N |
| ATOM | 3056 | C | GLN | D | 494 | 56.117 | 51.370 | 64.469 | 1.00 | 29.03 | D | C |
| ATOM | 3057 | O | GLN | D | 494 | 56.900 | 51.953 | 63.719 | 1.00 | 28.18 | D | O |
| ATOM | 3058 | N | ALA | D | 495 | 55.428 | 50.294 | 64.102 | 1.00 | 28.12 | D | N |
| ATOM | 3059 | CA | ALA | D | 495 | 55.539 | 49.737 | 62.764 | 1.00 | 25.99 | D | C |
| ATOM | 3060 | CB | ALA | D | 495 | 55.030 | 48.308 | 62.752 | 1.00 | 25.41 | D | C |
| ATOM | 3061 | C | ALA | D | 495 | 54.740 | 50.595 | 61.777 | 1.00 | 28.67 | D | C |
| ATOM | 3062 | O | ALA | D | 495 | 55.032 | 50.605 | 60.577 | 1.00 | 30.86 | D | O |
| ATOM | 3063 | N | HIS | D | 496 | 53.743 | 51.323 | 62.286 | 1.00 | 27.05 | D | N |
| ATOM | 3064 | CA | HIS | D | 496 | 52.903 | 52.190 | 61.454 | 1.00 | 24.32 | D | C |
| ATOM | 3065 | CB | HIS | D | 496 | 51.523 | 51.567 | 61.311 | 1.00 | 24.38 | D | C |
| ATOM | 3066 | CG | HIS | D | 496 | 51.561 | 50.095 | 61.055 | 1.00 | 25.98 | D | C |
| ATOM | 3067 | CD2 | HIS | D | 496 | 51.396 | 49.041 | 61.889 | 1.00 | 27.28 | D | C |
| ATOM | 3068 | ND1 | HIS | D | 496 | 51.796 | 49.564 | 59.806 | 1.00 | 28.06 | D | N |
| ATOM | 3069 | CE1 | HIS | D | 496 | 51.772 | 48.244 | 59.880 | 1.00 | 27.15 | D | C |
| ATOM | 3070 | NE2 | HIS | D | 496 | 51.531 | 47.901 | 61.134 | 1.00 | 27.52 | D | N |
| ATOM | 3071 | C | HIS | D | 496 | 52.777 | 53.578 | 62.071 | 1.00 | 23.14 | D | C |
| ATOM | 3072 | O | HIS | D | 496 | 51.700 | 53.990 | 62.487 | 1.00 | 24.05 | D | O |
| ATOM | 3073 | N | PRO | D | 497 | 53.876 | 54.329 | 62.095 | 1.00 | 21.09 | D | N |
| ATOM | 3074 | CD | PRO | D | 497 | 55.172 | 53.937 | 61.513 | 1.00 | 23.27 | D | C |
| ATOM | 3075 | CA | PRO | D | 497 | 53.914 | 55.671 | 62.665 | 1.00 | 23.02 | D | C |
| ATOM | 3076 | CB | PRO | D | 497 | 55.389 | 56.049 | 62.583 | 1.00 | 24.23 | D | C |
| ATOM | 3077 | CG | PRO | D | 497 | 55.929 | 55.225 | 61.458 | 1.00 | 21.50 | D | C |
| ATOM | 3078 | C | PRO | D | 497 | 53.021 | 56.716 | 62.014 | 1.00 | 24.95 | D | C |
| ATOM | 3079 | O | PRO | D | 497 | 52.393 | 57.516 | 62.711 | 1.00 | 28.13 | D | O |
| ATOM | 3080 | N | GLU | D | 498 | 52.966 | 56.733 | 60.687 | 1.00 | 25.32 | D | N |
| ATOM | 3081 | CA | GLU | D | 498 | 52.139 | 57.719 | 60.003 | 1.00 | 24.51 | D | C |
| ATOM | 3082 | CB | GLU | D | 498 | 52.453 | 57.753 | 58.502 | 1.00 | 23.97 | D | C |
| ATOM | 3083 | CG | GLU | D | 498 | 53.528 | 58.768 | 58.145 | 1.00 | 26.48 | D | C |
| ATOM | 3084 | CD | GLU | D | 498 | 53.492 | 59.193 | 56.694 | 1.00 | 31.95 | D | C |
| ATOM | 3085 | OE1 | GLU | D | 498 | 53.180 | 58.351 | 55.822 | 1.00 | 34.39 | D | O |
| ATOM | 3086 | OE2 | GLU | D | 498 | 53.782 | 60.377 | 56.422 | 1.00 | 36.45 | D | O |
| ATOM | 3087 | C | GLU | D | 498 | 50.671 | 57.415 | 60.229 | 1.00 | 22.24 | D | C |
| ATOM | 3088 | O | GLU | D | 498 | 49.882 | 58.316 | 60.527 | 1.00 | 22.26 | D | O |
| ATOM | 3089 | N | LEU | D | 499 | 50.302 | 56.150 | 60.077 | 1.00 | 19.96 | D | N |
| ATOM | 3090 | CA | LEU | D | 499 | 48.915 | 55.764 | 60.294 | 1.00 | 21.76 | D | C |
| ATOM | 3091 | CB | LEU | D | 499 | 48.697 | 54.295 | 59.920 | 1.00 | 16.02 | D | C |
| ATOM | 3092 | CG | LEU | D | 499 | 47.255 | 53.807 | 60.104 | 1.00 | 19.35 | D | C |
| ATOM | 3093 | CD1 | LEU | D | 499 | 46.275 | 54.790 | 59.461 | 1.00 | 14.86 | D | C |
| ATOM | 3094 | CD2 | LEU | D | 499 | 47.099 | 52.415 | 59.498 | 1.00 | 20.02 | D | C |
| ATOM | 3095 | C | LEU | D | 499 | 48.528 | 55.993 | 61.765 | 1.00 | 22.10 | D | C |
| ATOM | 3096 | O | LEU | D | 499 | 47.407 | 56.404 | 62.061 | 1.00 | 22.81 | D | O |
| ATOM | 3097 | N | SER | D | 500 | 49.466 | 55.741 | 62.676 | 1.00 | 20.87 | D | N |
| ATOM | 3098 | CA | SER | D | 500 | 49.221 | 55.922 | 64.103 | 1.00 | 19.25 | D | C |
| ATOM | 3099 | CB | SER | D | 500 | 50.421 | 55.429 | 64.919 | 1.00 | 20.35 | D | C |
| ATOM | 3100 | OG | SER | D | 500 | 50.521 | 54.013 | 64.877 | 1.00 | 17.47 | D | O |
| ATOM | 3101 | C | SER | D | 500 | 48.954 | 57.383 | 64.422 | 1.00 | 19.77 | D | C |
| ATOM | 3102 | O | SER | D | 500 | 48.089 | 57.693 | 65.238 | 1.00 | 20.85 | D | O |
| ATOM | 3103 | N | VAL | D | 501 | 49.692 | 58.283 | 63.779 | 1.00 | 18.96 | D | N |
| ATOM | 3104 | CA | VAL | D | 501 | 49.505 | 59.713 | 64.005 | 1.00 | 19.51 | D | C |
| ATOM | 3105 | CB | VAL | D | 501 | 50.660 | 60.532 | 63.361 | 1.00 | 17.23 | D | C |
| ATOM | 3106 | CG1 | VAL | D | 501 | 50.251 | 61.995 | 63.181 | 1.00 | 15.74 | D | C |
| ATOM | 3107 | CG2 | VAL | D | 501 | 51.882 | 60.453 | 64.246 | 1.00 | 15.59 | D | C |
| ATOM | 3108 | C | VAL | D | 501 | 48.149 | 60.181 | 63.442 | 1.00 | 20.88 | D | C |
| ATOM | 3109 | O | VAL | D | 501 | 47.415 | 60.934 | 64.084 | 1.00 | 21.61 | D | O |
| ATOM | 3110 | N | PHE | D | 502 | 47.831 | 59.720 | 62.241 | 1.00 | 19.70 | D | N |
| ATOM | 3111 | CA | PHE | D | 502 | 46.592 | 60.068 | 61.576 | 1.00 | 18.20 | D | C |
| ATOM | 3112 | CB | PHE | D | 502 | 46.554 | 59.353 | 60.216 | 1.00 | 19.03 | D | C |
| ATOM | 3113 | CG | PHE | D | 502 | 45.270 | 59.538 | 59.441 | 1.00 | 15.69 | D | C |
| ATOM | 3114 | CD1 | PHE | D | 502 | 44.786 | 60.809 | 59.154 | 1.00 | 15.45 | D | C |
| ATOM | 3115 | CD2 | PHE | D | 502 | 44.574 | 58.430 | 58.966 | 1.00 | 17.19 | D | C |
| ATOM | 3116 | CE1 | PHE | D | 502 | 43.617 | 60.984 | 58.399 | 1.00 | 18.37 | D | C |
| ATOM | 3117 | CE2 | PHE | D | 502 | 43.403 | 58.579 | 58.207 | 1.00 | 17.52 | D | C |
| ATOM | 3118 | CZ | PHE | D | 502 | 42.922 | 59.864 | 57.921 | 1.00 | 18.60 | D | C |
| ATOM | 3119 | C | PHE | D | 502 | 45.417 | 59.620 | 62.451 | 1.00 | 19.46 | D | C |
| ATOM | 3120 | O | PHE | D | 502 | 44.456 | 60.366 | 62.653 | 1.00 | 18.13 | D | O |
| ATOM | 3121 | N | LEU | D | 503 | 45.509 | 58.403 | 62.982 | 1.00 | 18.60 | D | N |
| ATOM | 3122 | CA | LEU | D | 503 | 44.443 | 57.864 | 63.814 | 1.00 | 17.60 | D | C |
| ATOM | 3123 | CB | LEU | D | 503 | 44.790 | 56.441 | 64.235 | 1.00 | 16.03 | D | C |
| ATOM | 3124 | CG | LEU | D | 503 | 44.580 | 55.415 | 63.118 | 1.00 | 16.18 | D | C |
| ATOM | 3125 | CD1 | LEU | D | 503 | 45.040 | 54.034 | 63.586 | 1.00 | 14.27 | D | C |
| ATOM | 3126 | CD2 | LEU | D | 503 | 43.121 | 55.389 | 62.712 | 1.00 | 14.11 | D | C |
| ATOM | 3127 | C | LEU | D | 503 | 44.129 | 58.736 | 65.036 | 1.00 | 18.10 | D | C |
| ATOM | 3128 | O | LEU | D | 503 | 43.001 | 58.736 | 65.532 | 1.00 | 18.09 | D | O |
| ATOM | 3129 | N | LYS | D | 504 | 45.117 | 59.489 | 65.506 | 1.00 | 17.77 | D | N |
| ATOM | 3130 | CA | LYS | D | 504 | 44.911 | 60.381 | 66.644 | 1.00 | 19.80 | D | C |
| ATOM | 3131 | CB | LYS | D | 504 | 46.247 | 60.902 | 67.182 | 1.00 | 17.96 | D | C |
| ATOM | 3132 | CG | LYS | D | 504 | 47.082 | 59.846 | 67.858 | 1.00 | 21.72 | D | C |
| ATOM | 3133 | CD | LYS | D | 504 | 48.486 | 60.372 | 68.139 | 1.00 | 24.89 | D | C |
| ATOM | 3134 | CE | LYS | D | 504 | 48.477 | 61.389 | 69.265 | 1.00 | 26.37 | D | C |
| ATOM | 3135 | NZ | LYS | D | 504 | 49.782 | 62.098 | 69.371 | 1.00 | 30.82 | D | N |
| ATOM | 3136 | C | LYS | D | 504 | 44.057 | 61.577 | 66.234 | 1.00 | 19.68 | D | C |
| ATOM | 3137 | O | LYS | D | 504 | 43.504 | 62.256 | 67.098 | 1.00 | 18.52 | D | O |
| ATOM | 3138 | N | HIS | D | 505 | 43.970 | 61.841 | 64.925 | 1.00 | 18.82 | D | N |
| ATOM | 3139 | CA | HIS | D | 505 | 43.189 | 62.965 | 64.405 | 1.00 | 13.28 | D | C |
| ATOM | 3140 | CB | HIS | D | 505 | 43.909 | 63.607 | 63.233 | 1.00 | 15.19 | D | C |
| ATOM | 3141 | CG | HIS | D | 505 | 45.199 | 64.257 | 63.603 | 1.00 | 18.78 | D | C |
| ATOM | 3142 | CD2 | HIS | D | 505 | 46.406 | 63.731 | 63.915 | 1.00 | 19.63 | D | C |
| ATOM | 3143 | ND1 | HIS | D | 505 | 45.353 | 65.627 | 63.652 | 1.00 | 24.56 | D | N |
| ATOM | 3144 | CE1 | HIS | D | 505 | 46.601 | 65.918 | 63.976 | 1.00 | 24.09 | D | C |
| ATOM | 3145 | NE2 | HIS | D | 505 | 47.261 | 64.784 | 64.142 | 1.00 | 22.03 | D | N |
| ATOM | 3146 | C | HIS | D | 505 | 41.799 | 62.552 | 63.947 | 1.00 | 13.09 | D | C |
| ATOM | 3147 | O | HIS | D | 505 | 41.019 | 63.388 | 63.499 | 1.00 | 12.90 | D | O |
| ATOM | 3148 | N | ILE | D | 506 | 41.492 | 61.265 | 64.041 | 1.00 | 11.53 | D | N |
| ATOM | 3149 | CA | ILE | D | 506 | 40.183 | 60.765 | 63.638 | 1.00 | 12.45 | D | C |
| ATOM | 3150 | CB | ILE | D | 506 | 40.289 | 59.372 | 62.984 | 1.00 | 10.42 | D | C |
| ATOM | 3151 | CG2 | ILE | D | 506 | 38.888 | 58.830 | 62.727 | 1.00 | 9.38 | D | C |
| ATOM | 3152 | CG1 | ILE | D | 506 | 41.116 | 59.448 | 61.687 | 1.00 | 8.75 | D | C |
| ATOM | 3153 | CD1 | ILE | D | 506 | 40.790 | 60.642 | 60.800 | 1.00 | 10.14 | D | C |
| ATOM | 3154 | C | ILE | D | 506 | 39.283 | 60.651 | 64.869 | 1.00 | 16.38 | D | C |
| ATOM | 3155 | O | ILE | D | 506 | 39.646 | 60.004 | 65.849 | 1.00 | 16.54 | D | O |
| ATOM | 3156 | N | THR | D | 507 | 38.098 | 61.259 | 64.815 | 1.00 | 17.47 | D | N |
| ATOM | 3157 | CA | THR | D | 507 | 37.169 | 61.232 | 65.953 | 1.00 | 14.54 | D | C |
| ATOM | 3158 | CB | THR | D | 507 | 36.524 | 62.627 | 66.180 | 1.00 | 13.89 | D | C |
| ATOM | 3159 | OG1 | THR | D | 507 | 35.599 | 62.900 | 65.117 | 1.00 | 15.34 | D | O |
| ATOM | 3160 | CG2 | THR | D | 507 | 37.589 | 63.727 | 66.231 | 1.00 | 9.60 | D | C |
| ATOM | 3161 | C | THR | D | 507 | 36.032 | 60.205 | 65.859 | 1.00 | 15.10 | D | C |
| ATOM | 3162 | O | THR | D | 507 | 35.426 | 59.867 | 66.881 | 1.00 | 11.04 | D | O |
| ATOM | 3163 | N | GLY | D | 508 | 35.740 | 59.720 | 64.647 | 1.00 | 12.42 | D | N |
| ATOM | 3164 | CA | GLY | D | 508 | 34.663 | 58.759 | 64.474 | 1.00 | 11.35 | D | C |
| ATOM | 3165 | C | GLY | D | 508 | 34.495 | 58.259 | 63.052 | 1.00 | 11.73 | D | C |
| ATOM | 3166 | O | GLY | D | 508 | 35.195 | 58.701 | 62.137 | 1.00 | 13.83 | D | O |
| ATOM | 3167 | N | PHE | D | 509 | 33.566 | 57.325 | 62.876 | 1.00 | 11.85 | D | N |
| ATOM | 3168 | CA | PHE | D | 509 | 33.262 | 56.730 | 61.577 | 1.00 | 12.86 | D | C |
| ATOM | 3169 | CB | PHE | D | 509 | 33.385 | 55.213 | 61.638 | 1.00 | 12.13 | D | C |
| ATOM | 3170 | CG | PHE | D | 509 | 34.786 | 54.735 | 61.760 | 1.00 | 15.55 | D | C |
| ATOM | 3171 | CD1 | PHE | D | 509 | 35.494 | 54.314 | 60.629 | 1.00 | 13.22 | D | C |
| ATOM | 3172 | CD2 | PHE | D | 509 | 35.412 | 54.717 | 63.002 | 1.00 | 12.55 | D | C |
| ATOM | 3173 | CE1 | PHE | D | 509 | 36.810 | 53.883 | 60.730 | 1.00 | 13.30 | D | C |
| ATOM | 3174 | CE2 | PHE | D | 509 | 36.725 | 54.290 | 63.120 | 1.00 | 17.12 | D | C |
| ATOM | 3175 | CZ | PHE | D | 509 | 37.433 | 53.869 | 61.974 | 1.00 | 18.40 | D | C |
| ATOM | 3176 | C | PHE | D | 509 | 31.841 | 57.058 | 61.151 | 1.00 | 14.32 | D | C |
| ATOM | 3177 | O | PHE | D | 509 | 30.927 | 57.118 | 61.981 | 1.00 | 14.48 | D | O |
| ATOM | 3178 | N | ASP | D | 510 | 31.661 | 57.253 | 59.850 | 1.00 | 13.72 | D | N |
| ATOM | 3179 | CA | ASP | D | 510 | 30.355 | 57.551 | 59.275 | 1.00 | 13.37 | D | C |
| ATOM | 3180 | CB | ASP | D | 510 | 30.413 | 58.920 | 58.576 | 1.00 | 14.32 | D | C |
| ATOM | 3181 | CG | ASP | D | 510 | 29.036 | 59.529 | 58.320 | 1.00 | 13.37 | D | C |
| ATOM | 3182 | OD1 | ASP | D | 510 | 28.038 | 58.789 | 58.168 | 1.00 | 16.88 | D | O |
| ATOM | 3183 | OD2 | ASP | D | 510 | 28.950 | 60.776 | 58.251 | 1.00 | 15.57 | D | O |
| ATOM | 3184 | C | ASP | D | 510 | 30.035 | 56.435 | 58.268 | 1.00 | 16.17 | D | C |
| ATOM | 3185 | O | ASP | D | 510 | 30.924 | 55.682 | 57.843 | 1.00 | 15.52 | D | O |
| ATOM | 3186 | N | SER | D | 511 | 28.760 | 56.303 | 57.922 | 1.00 | 16.91 | D | N |
| ATOM | 3187 | CA | SER | D | 511 | 28.330 | 55.316 | 56.937 | 1.00 | 17.58 | D | C |
| ATOM | 3188 | CB | SER | D | 511 | 27.497 | 54.221 | 57.584 | 1.00 | 14.93 | D | C |
| ATOM | 3189 | OG | SER | D | 511 | 27.053 | 53.306 | 56.605 | 1.00 | 13.63 | D | O |
| ATOM | 3190 | C | SER | D | 511 | 27.485 | 56.107 | 55.949 | 1.00 | 17.96 | D | C |
| ATOM | 3191 | O | SER | D | 511 | 26.574 | 56.817 | 56.353 | 1.00 | 15.94 | D | O |
| ATOM | 3192 | N | VAL | D | 512 | 27.801 | 55.994 | 54.662 | 1.00 | 19.61 | D | N |
| ATOM | 3193 | CA | VAL | D | 512 | 27.093 | 56.748 | 53.635 | 1.00 | 19.54 | D | C |
| ATOM | 3194 | CB | VAL | D | 512 | 27.947 | 57.955 | 53.175 | 1.00 | 20.88 | D | C |
| ATOM | 3195 | CG1 | VAL | D | 512 | 28.088 | 58.953 | 54.308 | 1.00 | 19.64 | D | C |
| ATOM | 3196 | CG2 | VAL | D | 512 | 29.345 | 57.484 | 52.749 | 1.00 | 20.25 | D | C |
| ATOM | 3197 | C | VAL | D | 512 | 26.680 | 55.945 | 52.404 | 1.00 | 19.81 | D | C |
| ATOM | 3198 | O | VAL | D | 512 | 27.304 | 54.944 | 52.058 | 1.00 | 16.14 | D | O |
| ATOM | 3199 | N | ASP | D | 513 | 25.608 | 56.417 | 51.762 | 1.00 | 24.96 | D | N |
| ATOM | 3200 | CA | ASP | D | 513 | 25.011 | 55.834 | 50.551 | 1.00 | 25.43 | D | C |
| ATOM | 3201 | CB | ASP | D | 513 | 24.948 | 54.299 | 50.620 | 1.00 | 26.32 | D | C |
| ATOM | 3202 | CG | ASP | D | 513 | 24.782 | 53.653 | 49.231 | 1.00 | 28.82 | D | C |
| ATOM | 3203 | OD1 | ASP | D | 513 | 25.082 | 54.318 | 48.210 | 1.00 | 27.72 | D | O |
| ATOM | 3204 | OD2 | ASP | D | 513 | 24.354 | 52.481 | 49.161 | 1.00 | 27.31 | D | O |
| ATOM | 3205 | C | ASP | D | 513 | 23.592 | 56.363 | 50.382 | 1.00 | 25.64 | D | C |
| ATOM | 3206 | O | ASP | D | 513 | 23.080 | 57.080 | 51.239 | 1.00 | 26.94 | D | O |
| ATOM | 3207 | N | ASP | D | 514 | 22.967 | 56.009 | 49.263 | 1.00 | 26.24 | D | N |
| ATOM | 3208 | CA | ASP | D | 514 | 21.592 | 56.401 | 48.970 | 1.00 | 23.79 | D | C |
| ATOM | 3209 | CB | ASP | D | 514 | 21.254 | 56.034 | 47.527 | 1.00 | 26.89 | D | C |
| ATOM | 3210 | CG | ASP | D | 514 | 19.848 | 56.439 | 47.121 | 1.00 | 31.24 | D | C |
| ATOM | 3211 | OD1 | ASP | D | 514 | 19.041 | 56.837 | 47.985 | 1.00 | 33.77 | D | O |
| ATOM | 3212 | OD2 | ASP | D | 514 | 19.544 | 56.356 | 45.912 | 1.00 | 35.70 | D | O |
| ATOM | 3213 | C | ASP | D | 514 | 20.752 | 55.579 | 49.930 | 1.00 | 23.87 | D | C |
| ATOM | 3214 | O | ASP | D | 514 | 20.568 | 54.372 | 49.732 | 1.00 | 21.88 | D | O |
| ATOM | 3215 | N | GLU | D | 515 | 20.252 | 56.231 | 50.973 | 1.00 | 23.14 | D | N |
| ATOM | 3216 | CA | GLU | D | 515 | 19.456 | 55.544 | 51.983 | 1.00 | 23.85 | D | C |
| ATOM | 3217 | CB | GLU | D | 515 | 19.294 | 56.441 | 53.217 | 1.00 | 23.83 | D | C |
| ATOM | 3218 | CG | GLU | D | 515 | 19.445 | 55.694 | 54.519 | 1.00 | 19.88 | D | C |
| ATOM | 3219 | CD | GLU | D | 515 | 19.135 | 56.556 | 55.710 | 1.00 | 15.74 | D | C |
| ATOM | 3220 | OE1 | GLU | D | 515 | 19.444 | 57.765 | 55.662 | 1.00 | 12.67 | D | O |
| ATOM | 3221 | OE2 | GLU | D | 515 | 18.581 | 56.017 | 56.690 | 1.00 | 12.44 | D | O |
| ATOM | 3222 | C | GLU | D | 515 | 18.084 | 55.067 | 51.513 | 1.00 | 24.96 | D | C |
| ATOM | 3223 | O | GLU | D | 515 | 17.479 | 54.180 | 52.131 | 1.00 | 23.53 | D | O |
| ATOM | 3224 | N | SER | D | 516 | 17.589 | 55.657 | 50.428 | 1.00 | 25.14 | D | N |
| ATOM | 3225 | CA | SER | D | 516 | 16.283 | 55.278 | 49.892 | 1.00 | 27.49 | D | C |
| ATOM | 3226 | CB | SER | D | 516 | 15.758 | 56.336 | 48.922 | 1.00 | 26.67 | D | C |
| ATOM | 3227 | OG | SER | D | 516 | 16.451 | 56.279 | 47.689 | 1.00 | 27.20 | D | O |
| ATOM | 3228 | C | SER | D | 516 | 16.361 | 53.961 | 49.170 | 1.00 | 29.80 | D | C |
| ATOM | 3229 | O | SER | D | 516 | 15.344 | 53.416 | 48.777 | 1.00 | 32.01 | D | O |
| ATOM | 3230 | N | LYS | D | 517 | 17.573 | 53.450 | 48.994 | 1.00 | 34.31 | D | N |
| ATOM | 3231 | CA | LYS | D | 517 | 17.760 | 52.188 | 48.304 | 1.00 | 38.20 | D | C |
| ATOM | 3232 | CB | LYS | D | 517 | 19.231 | 51.820 | 48.244 | 1.00 | 36.45 | D | C |
| ATOM | 3233 | CG | LYS | D | 517 | 19.717 | 51.566 | 46.846 | 1.00 | 35.25 | D | C |
| ATOM | 3234 | CD | LYS | D | 517 | 20.852 | 52.501 | 46.491 | 1.00 | 37.84 | D | C |
| ATOM | 3235 | CE | LYS | D | 517 | 22.072 | 52.249 | 47.373 | 1.00 | 39.26 | D | C |
| ATOM | 3236 | NZ | LYS | D | 517 | 23.024 | 51.283 | 46.760 | 1.00 | 39.12 | D | N |
| ATOM | 3237 | C | LYS | D | 517 | 16.984 | 51.034 | 48.912 | 1.00 | 45.05 | D | C |
| ATOM | 3238 | O | LYS | D | 517 | 16.574 | 51.053 | 50.083 | 1.00 | 47.89 | D | O |
| ATOM | 3239 | N | HIS | D | 518 | 16.812 | 50.023 | 48.072 | 1.00 | 50.94 | D | N |
| ATOM | 3240 | CA | HIS | D | 518 | 16.091 | 48.785 | 48.364 | 1.00 | 55.50 | D | C |
| ATOM | 3241 | CB | HIS | D | 518 | 15.500 | 48.277 | 47.057 | 1.00 | 59.89 | D | C |
| ATOM | 3242 | CG | HIS | D | 518 | 16.538 | 48.135 | 45.986 | 1.00 | 65.88 | D | C |
| ATOM | 3243 | CD2 | HIS | D | 518 | 17.122 | 49.061 | 45.183 | 1.00 | 65.86 | D | C |
| ATOM | 3244 | ND1 | HIS | D | 518 | 17.217 | 46.953 | 45.759 | 1.00 | 67.67 | D | N |
| ATOM | 3245 | CE1 | HIS | D | 518 | 18.173 | 47.157 | 44.870 | 1.00 | 68.11 | D | C |
| ATOM | 3246 | NE2 | HIS | D | 518 | 18.137 | 48.429 | 44.504 | 1.00 | 69.50 | D | N |
| ATOM | 3247 | C | HIS | D | 518 | 17.086 | 47.732 | 48.860 | 1.00 | 54.62 | D | C |
| ATOM | 3248 | O | HIS | D | 518 | 18.132 | 47.507 | 48.234 | 1.00 | 54.29 | D | O |
| ATOM | 3249 | N | SER | D | 519 | 16.776 | 47.082 | 49.970 | 1.00 | 53.64 | D | N |
| ATOM | 3250 | CA | SER | D | 519 | 17.672 | 46.040 | 50.449 | 1.00 | 52.91 | D | C |
| ATOM | 3251 | CB | SER | D | 519 | 17.917 | 46.175 | 51.950 | 1.00 | 52.76 | D | C |
| ATOM | 3252 | OG | SER | D | 519 | 18.429 | 44.961 | 52.468 | 1.00 | 50.12 | D | O |
| ATOM | 3253 | C | SER | D | 519 | 16.965 | 44.725 | 50.153 | 1.00 | 53.10 | D | C |
| ATOM | 3254 | O | SER | D | 519 | 17.484 | 43.872 | 49.431 | 1.00 | 50.86 | D | O |
| ATOM | 3255 | N | GLY | D | 520 | 15.759 | 44.598 | 50.707 | 1.00 | 53.89 | D | N |
| ATOM | 3256 | CA | GLY | D | 520 | 14.952 | 43.406 | 50.526 | 1.00 | 53.14 | D | C |
| ATOM | 3257 | C | GLY | D | 520 | 15.259 | 42.310 | 51.529 | 1.00 | 52.72 | D | C |
| ATOM | 3258 | O | GLY | D | 520 | 14.375 | 41.535 | 51.888 | 1.00 | 54.64 | D | O |
| ATOM | 3259 | N | HIS | D | 521 | 16.504 | 42.265 | 51.997 | 1.00 | 51.48 | D | N |
| ATOM | 3260 | CA | HIS | D | 521 | 16.965 | 41.241 | 52.936 | 1.00 | 50.43 | D | C |
| ATOM | 3261 | CB | HIS | D | 521 | 18.079 | 40.430 | 52.268 | 1.00 | 52.82 | D | C |
| ATOM | 3262 | CG | HIS | D | 521 | 19.023 | 41.269 | 51.455 | 1.00 | 55.69 | D | C |
| ATOM | 3263 | CD2 | HIS | D | 521 | 19.697 | 42.405 | 51.763 | 1.00 | 56.52 | D | C |
| ATOM | 3264 | ND1 | HIS | D | 521 | 19.334 | 40.988 | 50.141 | 1.00 | 56.59 | D | N |
| ATOM | 3265 | CE1 | HIS | D | 521 | 20.155 | 41.914 | 49.675 | 1.00 | 56.96 | D | C |
| ATOM | 3266 | NE2 | HIS | D | 521 | 20.391 | 42.785 | 50.640 | 1.00 | 57.08 | D | N |
| ATOM | 3267 | C | HIS | D | 521 | 17.503 | 41.831 | 54.240 | 1.00 | 48.12 | D | C |
| ATOM | 3268 | O | HIS | D | 521 | 18.687 | 42.157 | 54.329 | 1.00 | 49.13 | D | O |
| ATOM | 3269 | N | MET | D | 522 | 16.672 | 41.948 | 55.264 | 1.00 | 44.19 | D | N |
| ATOM | 3270 | CA | MET | D | 522 | 17.195 | 42.515 | 56.496 | 1.00 | 44.51 | D | C |
| ATOM | 3271 | CB | MET | D | 522 | 16.101 | 43.172 | 57.332 | 1.00 | 47.84 | D | C |
| ATOM | 3272 | CG | MET | D | 522 | 16.707 | 44.199 | 58.282 | 1.00 | 50.30 | D | C |
| ATOM | 3273 | SD | MET | D | 522 | 15.740 | 44.605 | 59.724 | 1.00 | 55.89 | D | S |
| ATOM | 3274 | CE | MET | D | 522 | 14.261 | 45.314 | 58.933 | 1.00 | 55.42 | D | C |
| ATOM | 3275 | C | MET | D | 522 | 17.985 | 41.580 | 57.399 | 1.00 | 40.03 | D | C |
| ATOM | 3276 | O | MET | D | 522 | 17.757 | 40.377 | 57.438 | 1.00 | 37.23 | D | O |
| ATOM | 3277 | N | PHE | D | 523 | 18.920 | 42.180 | 58.127 | 1.00 | 37.62 | D | N |
| ATOM | 3278 | CA | PHE | D | 523 | 19.777 | 41.480 | 59.067 | 1.00 | 33.89 | D | C |
| ATOM | 3279 | CB | PHE | D | 523 | 20.501 | 42.505 | 59.940 | 1.00 | 31.93 | D | C |
| ATOM | 3280 | CG | PHE | D | 523 | 21.585 | 41.924 | 60.794 | 1.00 | 29.46 | D | C |
| ATOM | 3281 | CD1 | PHE | D | 523 | 22.512 | 41.043 | 60.254 | 1.00 | 27.60 | D | C |
| ATOM | 3282 | CD2 | PHE | D | 523 | 21.688 | 42.274 | 62.142 | 1.00 | 27.55 | D | C |
| ATOM | 3283 | CE1 | PHE | D | 523 | 23.531 | 40.514 | 61.039 | 1.00 | 29.58 | D | C |
| ATOM | 3284 | CE2 | PHE | D | 523 | 22.703 | 41.755 | 62.940 | 1.00 | 26.24 | D | C |
| ATOM | 3285 | CZ | PHE | D | 523 | 23.628 | 40.873 | 62.390 | 1.00 | 29.29 | D | C |
| ATOM | 3286 | C | PHE | D | 523 | 18.990 | 40.523 | 59.953 | 1.00 | 32.81 | D | C |
| ATOM | 3287 | O | PHE | D | 523 | 17.978 | 40.891 | 60.547 | 1.00 | 31.81 | D | O |
| ATOM | 3288 | N | SER | D | 524 | 19.471 | 39.290 | 60.041 | 1.00 | 32.46 | D | N |
| ATOM | 3289 | CA | SER | D | 524 | 18.830 | 38.283 | 60.861 | 1.00 | 33.16 | D | C |
| ATOM | 3290 | CB | SER | D | 524 | 17.628 | 37.693 | 60.125 | 1.00 | 34.63 | D | C |
| ATOM | 3291 | OG | SER | D | 524 | 17.932 | 36.405 | 59.606 | 1.00 | 35.15 | D | O |
| ATOM | 3292 | C | SER | D | 524 | 19.799 | 37.163 | 61.235 | 1.00 | 35.57 | D | C |
| ATOM | 3293 | O | SER | D | 524 | 20.998 | 37.212 | 60.939 | 1.00 | 35.40 | D | O |
| ATOM | 3294 | N | SER | D | 525 | 19.261 | 36.152 | 61.901 | 1.00 | 36.99 | D | N |
| ATOM | 3295 | CA | SER | D | 525 | 20.035 | 34.999 | 62.321 | 1.00 | 38.52 | D | C |
| ATOM | 3296 | CB | SER | D | 525 | 19.216 | 34.168 | 63.303 | 1.00 | 39.62 | D | C |
| ATOM | 3297 | OG | SER | D | 525 | 19.970 | 33.911 | 64.472 | 1.00 | 45.97 | D | O |
| ATOM | 3298 | C | SER | D | 525 | 20.407 | 34.134 | 61.120 | 1.00 | 38.52 | D | C |
| ATOM | 3299 | O | SER | D | 525 | 21.411 | 33.412 | 61.143 | 1.00 | 37.13 | D | O |
| ATOM | 3300 | N | LYS | D | 526 | 19.580 | 34.207 | 60.081 | 1.00 | 37.49 | D | N |
| ATOM | 3301 | CA | LYS | D | 526 | 19.796 | 33.443 | 58.860 | 1.00 | 38.89 | D | C |
| ATOM | 3302 | CB | LYS | D | 526 | 18.485 | 33.308 | 58.081 | 1.00 | 42.74 | D | C |
| ATOM | 3303 | CG | LYS | D | 526 | 17.236 | 33.235 | 58.946 | 1.00 | 47.89 | D | C |
| ATOM | 3304 | CD | LYS | D | 526 | 16.955 | 31.799 | 59.376 | 1.00 | 51.22 | D | C |
| ATOM | 3305 | CE | LYS | D | 526 | 15.451 | 31.510 | 59.437 | 1.00 | 54.15 | D | C |
| ATOM | 3306 | NZ | LYS | D | 526 | 15.080 | 30.261 | 58.692 | 1.00 | 54.43 | D | N |
| ATOM | 3307 | C | LYS | D | 526 | 20.839 | 34.103 | 57.966 | 1.00 | 36.19 | D | C |
| ATOM | 3308 | O | LYS | D | 526 | 21.507 | 33.434 | 57.184 | 1.00 | 37.26 | D | O |
| ATOM | 3309 | N | SER | D | 527 | 20.969 | 35.416 | 58.082 | 1.00 | 33.08 | D | N |
| ATOM | 3310 | CA | SER | D | 527 | 21.920 | 36.163 | 57.275 | 1.00 | 31.13 | D | C |
| ATOM | 3311 | CB | SER | D | 527 | 21.984 | 37.617 | 57.763 | 1.00 | 31.39 | D | C |
| ATOM | 3312 | OG | SER | D | 527 | 20.851 | 38.357 | 57.336 | 1.00 | 30.66 | D | O |
| ATOM | 3313 | C | SER | D | 527 | 23.324 | 35.561 | 57.286 | 1.00 | 29.48 | D | C |
| ATOM | 3314 | O | SER | D | 527 | 23.878 | 35.268 | 58.340 | 1.00 | 32.28 | D | O |
| ATOM | 3315 | N | PRO | D | 528 | 23.908 | 35.341 | 56.102 | 1.00 | 28.04 | D | N |
| ATOM | 3316 | CD | PRO | D | 528 | 23.314 | 35.536 | 54.768 | 1.00 | 26.79 | D | C |
| ATOM | 3317 | CA | PRO | D | 528 | 25.260 | 34.777 | 56.031 | 1.00 | 26.38 | D | C |
| ATOM | 3318 | CB | PRO | D | 528 | 25.515 | 34.606 | 54.531 | 1.00 | 26.70 | D | C |
| ATOM | 3319 | CG | PRO | D | 528 | 24.493 | 35.420 | 53.845 | 1.00 | 26.67 | D | C |
| ATOM | 3320 | C | PRO | D | 528 | 26.293 | 35.698 | 56.655 | 1.00 | 25.41 | D | C |
| ATOM | 3321 | O | PRO | D | 528 | 26.129 | 36.915 | 56.634 | 1.00 | 24.37 | D | O |
| ATOM | 3322 | N | LYS | D | 529 | 27.355 | 35.120 | 57.206 | 1.00 | 24.41 | D | N |
| ATOM | 3323 | CA | LYS | D | 529 | 28.409 | 35.927 | 57.805 | 1.00 | 26.33 | D | C |
| ATOM | 3324 | CB | LYS | D | 529 | 29.427 | 35.054 | 58.548 | 1.00 | 25.00 | D | C |
| ATOM | 3325 | CG | LYS | D | 529 | 28.807 | 34.032 | 59.487 | 1.00 | 27.69 | D | C |
| ATOM | 3326 | CD | LYS | D | 529 | 28.582 | 34.584 | 60.891 | 1.00 | 29.48 | D | C |
| ATOM | 3327 | CE | LYS | D | 529 | 27.095 | 34.697 | 61.205 | 1.00 | 33.10 | D | C |
| ATOM | 3328 | NZ | LYS | D | 529 | 26.582 | 33.633 | 62.112 | 1.00 | 31.64 | D | N |
| ATOM | 3329 | C | LYS | D | 529 | 29.078 | 36.643 | 56.645 | 1.00 | 25.63 | D | C |
| ATOM | 3330 | O | LYS | D | 529 | 28.899 | 36.251 | 55.493 | 1.00 | 26.89 | D | O |
| ATOM | 3331 | N | PRO | D | 530 | 29.828 | 37.721 | 56.929 | 1.00 | 24.77 | D | N |
| ATOM | 3332 | CD | PRO | D | 530 | 30.033 | 38.333 | 58.257 | 1.00 | 21.26 | D | C |
| ATOM | 3333 | CA | PRO | D | 530 | 30.511 | 38.480 | 55.880 | 1.00 | 22.90 | D | C |
| ATOM | 3334 | CB | PRO | D | 530 | 31.367 | 39.473 | 56.669 | 1.00 | 19.63 | D | C |
| ATOM | 3335 | CG | PRO | D | 530 | 30.583 | 39.694 | 57.922 | 1.00 | 18.66 | D | C |
| ATOM | 3336 | C | PRO | D | 530 | 31.328 | 37.658 | 54.879 | 1.00 | 23.81 | D | C |
| ATOM | 3337 | O | PRO | D | 530 | 31.185 | 37.827 | 53.666 | 1.00 | 21.73 | D | O |
| ATOM | 3338 | N | GLN | D | 531 | 32.190 | 36.779 | 55.379 | 1.00 | 24.81 | D | N |
| ATOM | 3339 | CA | GLN | D | 531 | 33.025 | 35.976 | 54.500 | 1.00 | 27.33 | D | C |
| ATOM | 3340 | CB | GLN | D | 531 | 34.046 | 35.176 | 55.318 | 1.00 | 28.50 | D | C |
| ATOM | 3341 | CG | GLN | D | 531 | 33.445 | 34.035 | 56.142 | 1.00 | 34.04 | D | C |
| ATOM | 3342 | CD | GLN | D | 531 | 32.982 | 34.471 | 57.540 | 1.00 | 39.19 | D | C |
| ATOM | 3343 | OE1 | GLN | D | 531 | 32.936 | 35.676 | 57.861 | 1.00 | 33.27 | D | O |
| ATOM | 3344 | NE2 | GLN | D | 531 | 32.640 | 33.482 | 58.382 | 1.00 | 37.71 | D | N |
| ATOM | 3345 | C | GLN | D | 531 | 32.165 | 35.048 | 53.652 | 1.00 | 27.48 | D | C |
| ATOM | 3346 | O | GLN | D | 531 | 32.605 | 34.564 | 52.615 | 1.00 | 29.05 | D | O |
| ATOM | 3347 | N | GLU | D | 532 | 30.932 | 34.814 | 54.094 | 1.00 | 28.71 | D | N |
| ATOM | 3348 | CA | GLU | D | 532 | 29.994 | 33.955 | 53.375 | 1.00 | 29.53 | D | C |
| ATOM | 3349 | CB | GLU | D | 532 | 29.067 | 33.241 | 54.354 | 1.00 | 30.12 | D | C |
| ATOM | 3350 | CG | GLU | D | 532 | 29.742 | 32.187 | 55.211 | 1.00 | 40.25 | D | C |
| ATOM | 3351 | CD | GLU | D | 532 | 28.925 | 31.836 | 56.471 | 1.00 | 47.13 | D | C |
| ATOM | 3352 | OE1 | GLU | D | 532 | 27.688 | 32.102 | 56.505 | 1.00 | 44.41 | D | O |
| ATOM | 3353 | OE2 | GLU | D | 532 | 29.532 | 31.292 | 57.432 | 1.00 | 48.71 | D | O |
| ATOM | 3354 | C | GLU | D | 532 | 29.139 | 34.747 | 52.382 | 1.00 | 28.74 | D | C |
| ATOM | 3355 | O | GLU | D | 532 | 28.474 | 34.165 | 51.533 | 1.00 | 28.45 | D | O |
| ATOM | 3356 | N | TRP | D | 533 | 29.138 | 36.073 | 52.509 | 1.00 | 28.74 | D | N |
| ATOM | 3357 | CA | TRP | D | 533 | 28.368 | 36.939 | 51.618 | 1.00 | 24.82 | D | C |
| ATOM | 3358 | CB | TRP | D | 533 | 28.065 | 38.270 | 52.303 | 1.00 | 24.68 | D | C |
| ATOM | 3359 | CG | TRP | D | 533 | 27.048 | 39.084 | 51.582 | 1.00 | 23.07 | D | C |
| ATOM | 3360 | CD2 | TRP | D | 533 | 25.689 | 39.297 | 51.974 | 1.00 | 21.76 | D | C |
| ATOM | 3361 | CE2 | TRP | D | 533 | 25.097 | 40.119 | 50.993 | 1.00 | 21.95 | D | C |
| ATOM | 3362 | CE3 | TRP | D | 533 | 24.911 | 38.872 | 53.064 | 1.00 | 23.91 | D | C |
| ATOM | 3363 | CD1 | TRP | D | 533 | 27.223 | 39.769 | 50.410 | 1.00 | 19.27 | D | C |
| ATOM | 3364 | NE1 | TRP | D | 533 | 26.058 | 40.390 | 50.052 | 1.00 | 22.27 | D | N |
| ATOM | 3365 | CZ2 | TRP | D | 533 | 23.755 | 40.530 | 51.064 | 1.00 | 22.83 | D | C |
| ATOM | 3366 | CZ3 | TRP | D | 533 | 23.575 | 39.278 | 53.139 | 1.00 | 20.46 | D | C |
| ATOM | 3367 | CH2 | TRP | D | 533 | 23.012 | 40.101 | 52.142 | 1.00 | 21.65 | D | C |
| ATOM | 3368 | C | TRP | D | 533 | 29.201 | 37.179 | 50.363 | 1.00 | 23.20 | D | C |
| ATOM | 3369 | O | TRP | D | 533 | 29.952 | 38.149 | 50.275 | 1.00 | 18.88 | D | O |
| ATOM | 3370 | N | THR | D | 534 | 29.050 | 36.278 | 49.400 | 1.00 | 23.43 | D | N |
| ATOM | 3371 | CA | THR | D | 534 | 29.793 | 36.341 | 48.155 | 1.00 | 24.34 | D | C |
| ATOM | 3372 | CB | THR | D | 534 | 30.327 | 34.958 | 47.774 | 1.00 | 23.14 | D | C |
| ATOM | 3373 | OG1 | THR | D | 534 | 29.244 | 34.028 | 47.836 | 1.00 | 26.73 | D | O |
| ATOM | 3374 | CG2 | THR | D | 534 | 31.425 | 34.506 | 48.717 | 1.00 | 22.26 | D | C |
| ATOM | 3375 | C | THR | D | 534 | 28.944 | 36.847 | 46.984 | 1.00 | 25.85 | D | C |
| ATOM | 3376 | O | THR | D | 534 | 29.490 | 37.170 | 45.921 | 1.00 | 24.78 | D | O |
| ATOM | 3377 | N | LEU | D | 535 | 27.625 | 36.907 | 47.162 | 1.00 | 23.25 | D | N |
| ATOM | 3378 | CA | LEU | D | 535 | 26.762 | 37.374 | 46.086 | 1.00 | 25.44 | D | C |
| ATOM | 3379 | CB | LEU | D | 535 | 25.296 | 37.146 | 46.427 | 1.00 | 25.46 | D | C |
| ATOM | 3380 | CG | LEU | D | 535 | 24.777 | 37.967 | 47.599 | 1.00 | 31.62 | D | C |
| ATOM | 3381 | CD1 | LEU | D | 535 | 23.275 | 38.091 | 47.497 | 1.00 | 31.80 | D | C |
| ATOM | 3382 | CD2 | LEU | D | 535 | 25.165 | 37.296 | 48.915 | 1.00 | 37.15 | D | C |
| ATOM | 3383 | C | LEU | D | 535 | 27.014 | 38.850 | 45.765 | 1.00 | 27.04 | D | C |
| ATOM | 3384 | O | LEU | D | 535 | 27.756 | 39.546 | 46.465 | 1.00 | 28.36 | D | O |
| ATOM | 3385 | N | GLU | D | 536 | 26.401 | 39.324 | 44.694 | 1.00 | 27.76 | D | N |
| ATOM | 3386 | CA | GLU | D | 536 | 26.595 | 40.696 | 44.264 | 1.00 | 30.53 | D | C |
| ATOM | 3387 | CB | GLU | D | 536 | 26.313 | 40.810 | 42.769 | 1.00 | 33.73 | D | C |
| ATOM | 3388 | CG | GLU | D | 536 | 27.398 | 41.534 | 42.008 | 1.00 | 42.75 | D | C |
| ATOM | 3389 | CD | GLU | D | 536 | 27.323 | 41.275 | 40.511 | 1.00 | 46.40 | D | C |
| ATOM | 3390 | OE1 | GLU | D | 536 | 26.821 | 42.162 | 39.781 | 1.00 | 50.24 | D | O |
| ATOM | 3391 | OE2 | GLU | D | 536 | 27.761 | 40.190 | 40.066 | 1.00 | 44.65 | D | O |
| ATOM | 3392 | C | GLU | D | 536 | 25.739 | 41.695 | 45.016 | 1.00 | 28.76 | D | C |
| ATOM | 3393 | O | GLU | D | 536 | 26.075 | 42.882 | 45.066 | 1.00 | 27.04 | D | O |
| ATOM | 3394 | N | LYS | D | 537 | 24.637 | 41.212 | 45.585 | 1.00 | 26.85 | D | N |
| ATOM | 3395 | CA | LYS | D | 537 | 23.711 | 42.048 | 46.338 | 1.00 | 27.36 | D | C |
| ATOM | 3396 | CB | LYS | D | 537 | 22.570 | 41.205 | 46.902 | 1.00 | 31.40 | D | C |
| ATOM | 3397 | CG | LYS | D | 537 | 21.319 | 41.216 | 46.053 | 1.00 | 39.64 | D | C |
| ATOM | 3398 | CD | LYS | D | 537 | 20.445 | 42.428 | 46.358 | 1.00 | 44.21 | D | C |
| ATOM | 3399 | CE | LYS | D | 537 | 19.196 | 42.437 | 45.480 | 1.00 | 47.63 | D | C |
| ATOM | 3400 | NZ | LYS | D | 537 | 18.961 | 43.766 | 44.829 | 1.00 | 51.21 | D | N |
| ATOM | 3401 | C | LYS | D | 537 | 24.400 | 42.764 | 47.487 | 1.00 | 26.32 | D | C |
| ATOM | 3402 | O | LYS | D | 537 | 25.280 | 42.210 | 48.143 | 1.00 | 27.12 | D | O |
| ATOM | 3403 | N | ASN | D | 538 | 23.985 | 44.001 | 47.725 | 1.00 | 24.35 | D | N |
| ATOM | 3404 | CA | ASN | D | 538 | 24.544 | 44.811 | 48.801 | 1.00 | 20.76 | D | C |
| ATOM | 3405 | CB | ASN | D | 538 | 24.292 | 46.293 | 48.521 | 1.00 | 18.12 | D | C |
| ATOM | 3406 | CG | ASN | D | 538 | 25.307 | 47.197 | 49.184 | 1.00 | 14.89 | D | C |
| ATOM | 3407 | OD1 | ASN | D | 538 | 26.439 | 46.800 | 49.417 | 1.00 | 17.79 | D | O |
| ATOM | 3408 | ND2 | ASN | D | 538 | 24.901 | 48.424 | 49.493 | 1.00 | 15.96 | D | N |
| ATOM | 3409 | C | ASN | D | 538 | 23.857 | 44.448 | 50.102 | 1.00 | 19.86 | D | C |
| ATOM | 3410 | O | ASN | D | 538 | 22.630 | 44.372 | 50.144 | 1.00 | 20.40 | D | O |
| ATOM | 3411 | N | PRO | D | 539 | 24.631 | 44.157 | 51.166 | 1.00 | 18.84 | D | N |
| ATOM | 3412 | CD | PRO | D | 539 | 26.100 | 44.046 | 51.256 | 1.00 | 17.55 | D | C |
| ATOM | 3413 | CA | PRO | D | 539 | 23.972 | 43.825 | 52.436 | 1.00 | 18.49 | D | C |
| ATOM | 3414 | CB | PRO | D | 539 | 25.142 | 43.622 | 53.404 | 1.00 | 16.42 | D | C |
| ATOM | 3415 | CG | PRO | D | 539 | 26.315 | 43.285 | 52.532 | 1.00 | 14.27 | D | C |
| ATOM | 3416 | C | PRO | D | 539 | 23.070 | 45.010 | 52.852 | 1.00 | 17.74 | D | C |
| ATOM | 3417 | O | PRO | D | 539 | 23.290 | 46.138 | 52.422 | 1.00 | 15.22 | D | O |
| ATOM | 3418 | N | SER | D | 540 | 22.050 | 44.751 | 53.663 | 1.00 | 18.23 | D | N |
| ATOM | 3419 | CA | SER | D | 540 | 21.159 | 45.814 | 54.146 | 1.00 | 18.36 | D | C |
| ATOM | 3420 | CB | SER | D | 540 | 19.986 | 45.219 | 54.937 | 1.00 | 20.01 | D | C |
| ATOM | 3421 | OG | SER | D | 540 | 20.431 | 44.671 | 56.168 | 1.00 | 23.45 | D | O |
| ATOM | 3422 | C | SER | D | 540 | 21.877 | 46.827 | 55.055 | 1.00 | 17.45 | D | C |
| ATOM | 3423 | O | SER | D | 540 | 23.012 | 46.606 | 55.502 | 1.00 | 15.26 | D | O |
| ATOM | 3424 | N | TYR | D | 541 | 21.192 | 47.941 | 55.309 | 1.00 | 15.98 | D | N |
| ATOM | 3425 | CA | TYR | D | 541 | 21.690 | 49.018 | 56.158 | 1.00 | 16.42 | D | C |
| ATOM | 3426 | CB | TYR | D | 541 | 20.620 | 50.116 | 56.234 | 1.00 | 17.33 | D | C |
| ATOM | 3427 | CG | TYR | D | 541 | 20.963 | 51.318 | 57.093 | 1.00 | 18.20 | D | C |
| ATOM | 3428 | CD1 | TYR | D | 541 | 20.783 | 51.283 | 58.471 | 1.00 | 18.21 | D | C |
| ATOM | 3429 | CE1 | TYR | D | 541 | 21.116 | 52.383 | 59.261 | 1.00 | 18.22 | D | C |
| ATOM | 3430 | CD2 | TYR | D | 541 | 21.475 | 52.484 | 56.524 | 1.00 | 13.66 | D | C |
| ATOM | 3431 | CE2 | TYR | D | 541 | 21.808 | 53.579 | 57.296 | 1.00 | 13.79 | D | C |
| ATOM | 3432 | CZ | TYR | D | 541 | 21.634 | 53.527 | 58.668 | 1.00 | 17.34 | D | C |
| ATOM | 3433 | OH | TYR | D | 541 | 22.019 | 54.593 | 59.454 | 1.00 | 14.63 | D | O |
| ATOM | 3434 | C | TYR | D | 541 | 22.040 | 48.491 | 57.555 | 1.00 | 14.52 | D | C |
| ATOM | 3435 | O | TYR | D | 541 | 23.108 | 48.774 | 58.080 | 1.00 | 15.69 | D | O |
| ATOM | 3436 | N | THR | D | 542 | 21.144 | 47.714 | 58.149 | 1.00 | 15.47 | D | N |
| ATOM | 3437 | CA | THR | D | 542 | 21.387 | 47.140 | 59.477 | 1.00 | 17.79 | D | C |
| ATOM | 3438 | CB | THR | D | 542 | 20.139 | 46.405 | 59.997 | 1.00 | 16.71 | D | C |
| ATOM | 3439 | OG1 | THR | D | 542 | 19.087 | 47.356 | 60.175 | 1.00 | 15.63 | D | O |
| ATOM | 3440 | CG2 | THR | D | 542 | 20.425 | 45.728 | 61.335 | 1.00 | 16.88 | D | C |
| ATOM | 3441 | C | THR | D | 542 | 22.583 | 46.177 | 59.486 | 1.00 | 18.46 | D | C |
| ATOM | 3442 | O | THR | D | 542 | 23.362 | 46.146 | 60.458 | 1.00 | 18.10 | D | O |
| ATOM | 3443 | N | TYR | D | 543 | 22.732 | 45.409 | 58.406 | 1.00 | 17.05 | D | N |
| ATOM | 3444 | CA | TYR | D | 543 | 23.852 | 44.468 | 58.265 | 1.00 | 17.79 | D | C |
| ATOM | 3445 | CB | TYR | D | 543 | 23.756 | 43.736 | 56.917 | 1.00 | 18.18 | D | C |
| ATOM | 3446 | CG | TYR | D | 543 | 24.699 | 42.563 | 56.755 | 1.00 | 14.78 | D | C |
| ATOM | 3447 | CD1 | TYR | D | 543 | 26.046 | 42.761 | 56.456 | 1.00 | 14.60 | D | C |
| ATOM | 3448 | CE1 | TYR | D | 543 | 26.915 | 41.677 | 56.307 | 1.00 | 17.18 | D | C |
| ATOM | 3449 | CD2 | TYR | D | 543 | 24.240 | 41.253 | 56.904 | 1.00 | 17.03 | D | C |
| ATOM | 3450 | CE2 | TYR | D | 543 | 25.099 | 40.157 | 56.759 | 1.00 | 18.37 | D | C |
| ATOM | 3451 | CZ | TYR | D | 543 | 26.428 | 40.379 | 56.458 | 1.00 | 18.92 | D | C |
| ATOM | 3452 | OH | TYR | D | 543 | 27.254 | 39.304 | 56.264 | 1.00 | 22.32 | D | O |
| ATOM | 3453 | C | TYR | D | 543 | 25.158 | 45.269 | 58.336 | 1.00 | 16.70 | D | C |
| ATOM | 3454 | O | TYR | D | 543 | 26.094 | 44.921 | 59.059 | 1.00 | 17.27 | D | O |
| ATOM | 3455 | N | TYR | D | 544 | 25.212 | 46.351 | 57.576 | 1.00 | 16.08 | D | N |
| ATOM | 3456 | CA | TYR | D | 544 | 26.383 | 47.210 | 57.577 | 1.00 | 17.89 | D | C |
| ATOM | 3457 | CB | TYR | D | 544 | 26.189 | 48.369 | 56.564 | 1.00 | 17.12 | D | C |
| ATOM | 3458 | CG | TYR | D | 544 | 26.685 | 48.130 | 55.137 | 1.00 | 17.29 | D | C |
| ATOM | 3459 | CD1 | TYR | D | 544 | 25.826 | 47.621 | 54.153 | 1.00 | 17.17 | D | C |
| ATOM | 3460 | CE1 | TYR | D | 544 | 26.239 | 47.495 | 52.825 | 1.00 | 16.14 | D | C |
| ATOM | 3461 | CD2 | TYR | D | 544 | 27.978 | 48.494 | 54.758 | 1.00 | 13.87 | D | C |
| ATOM | 3462 | CE2 | TYR | D | 544 | 28.405 | 48.372 | 53.441 | 1.00 | 19.28 | D | C |
| ATOM | 3463 | CZ | TYR | D | 544 | 27.526 | 47.877 | 52.475 | 1.00 | 20.08 | D | C |
| ATOM | 3464 | OH | TYR | D | 544 | 27.928 | 47.802 | 51.157 | 1.00 | 21.45 | D | O |
| ATOM | 3465 | C | TYR | D | 544 | 26.587 | 47.806 | 58.998 | 1.00 | 18.49 | D | C |
| ATOM | 3466 | O | TYR | D | 544 | 27.697 | 47.803 | 59.541 | 1.00 | 18.01 | D | O |
| ATOM | 3467 | N | ALA | D | 545 | 25.506 | 48.326 | 59.581 | 1.00 | 17.70 | D | N |
| ATOM | 3468 | CA | ALA | D | 545 | 25.565 | 48.955 | 60.897 | 1.00 | 16.71 | D | C |
| ATOM | 3469 | CB | ALA | D | 545 | 24.195 | 49.526 | 61.269 | 1.00 | 15.35 | D | C |
| ATOM | 3470 | C | ALA | D | 545 | 26.042 | 47.998 | 61.979 | 1.00 | 15.29 | D | C |
| ATOM | 3471 | O | ALA | D | 545 | 26.882 | 48.358 | 62.801 | 1.00 | 16.33 | D | O |
| ATOM | 3472 | N | TYR | D | 546 | 25.529 | 46.776 | 61.979 | 1.00 | 12.93 | D | N |
| ATOM | 3473 | CA | TYR | D | 546 | 25.967 | 45.842 | 62.992 | 1.00 | 15.83 | D | C |
| ATOM | 3474 | CB | TYR | D | 546 | 25.239 | 44.497 | 62.883 | 1.00 | 16.14 | D | C |
| ATOM | 3475 | CG | TYR | D | 546 | 25.797 | 43.494 | 63.876 | 1.00 | 21.92 | D | C |
| ATOM | 3476 | CD1 | TYR | D | 546 | 25.449 | 43.557 | 65.228 | 1.00 | 26.38 | D | C |
| ATOM | 3477 | CE1 | TYR | D | 546 | 26.063 | 42.734 | 66.179 | 1.00 | 24.39 | D | C |
| ATOM | 3478 | CD2 | TYR | D | 546 | 26.769 | 42.569 | 63.496 | 1.00 | 22.62 | D | C |
| ATOM | 3479 | CE2 | TYR | D | 546 | 27.388 | 41.745 | 64.436 | 1.00 | 25.57 | D | C |
| ATOM | 3480 | CZ | TYR | D | 546 | 27.030 | 41.839 | 65.776 | 1.00 | 27.49 | D | C |
| ATOM | 3481 | OH | TYR | D | 546 | 27.668 | 41.059 | 66.710 | 1.00 | 28.52 | D | O |
| ATOM | 3482 | C | TYR | D | 546 | 27.471 | 45.591 | 62.929 | 1.00 | 17.14 | D | C |
| ATOM | 3483 | O | TYR | D | 546 | 28.175 | 45.697 | 63.936 | 1.00 | 19.12 | D | O |
| ATOM | 3484 | N | TYR | D | 547 | 27.975 | 45.256 | 61.749 | 1.00 | 17.82 | D | N |
| ATOM | 3485 | CA | TYR | D | 547 | 29.394 | 44.965 | 61.625 | 1.00 | 15.68 | D | C |
| ATOM | 3486 | CB | TYR | D | 547 | 29.652 | 44.262 | 60.289 | 1.00 | 15.57 | D | C |
| ATOM | 3487 | CG | TYR | D | 547 | 29.167 | 42.827 | 60.346 | 1.00 | 14.74 | D | C |
| ATOM | 3488 | CD1 | TYR | D | 547 | 29.869 | 41.867 | 61.081 | 1.00 | 15.14 | D | C |
| ATOM | 3489 | CE1 | TYR | D | 547 | 29.373 | 40.572 | 61.237 | 1.00 | 13.67 | D | C |
| ATOM | 3490 | CD2 | TYR | D | 547 | 27.957 | 42.451 | 59.762 | 1.00 | 12.57 | D | C |
| ATOM | 3491 | CE2 | TYR | D | 547 | 27.451 | 41.159 | 59.907 | 1.00 | 9.62 | D | C |
| ATOM | 3492 | CZ | TYR | D | 547 | 28.166 | 40.229 | 60.648 | 1.00 | 14.32 | D | C |
| ATOM | 3493 | OH | TYR | D | 547 | 27.678 | 38.955 | 60.809 | 1.00 | 14.22 | D | O |
| ATOM | 3494 | C | TYR | D | 547 | 30.323 | 46.151 | 61.839 | 1.00 | 16.51 | D | C |
| ATOM | 3495 | O | TYR | D | 547 | 31.478 | 45.966 | 62.234 | 1.00 | 17.87 | D | O |
| ATOM | 3496 | N | MET | D | 548 | 29.836 | 47.368 | 61.596 | 1.00 | 16.66 | D | N |
| ATOM | 3497 | CA | MET | D | 548 | 30.669 | 48.540 | 61.828 | 1.00 | 16.31 | D | C |
| ATOM | 3498 | CB | MET | D | 548 | 30.102 | 49.742 | 61.096 | 1.00 | 17.02 | D | C |
| ATOM | 3499 | CG | MET | D | 548 | 30.616 | 49.832 | 59.673 | 1.00 | 19.95 | D | C |
| ATOM | 3500 | SD | MET | D | 548 | 30.470 | 51.476 | 59.021 | 1.00 | 33.68 | D | S |
| ATOM | 3501 | CE | MET | D | 548 | 32.106 | 52.166 | 59.416 | 1.00 | 25.75 | D | C |
| ATOM | 3502 | C | MET | D | 548 | 30.710 | 48.781 | 63.340 | 1.00 | 18.04 | D | C |
| ATOM | 3503 | O | MET | D | 548 | 31.770 | 49.056 | 63.919 | 1.00 | 16.65 | D | O |
| ATOM | 3504 | N | TYR | D | 549 | 29.552 | 48.644 | 63.983 | 1.00 | 15.42 | D | N |
| ATOM | 3505 | CA | TYR | D | 549 | 29.480 | 48.800 | 65.425 | 1.00 | 15.98 | D | C |
| ATOM | 3506 | CB | TYR | D | 549 | 28.037 | 48.623 | 65.914 | 1.00 | 15.78 | D | C |
| ATOM | 3507 | CG | TYR | D | 549 | 27.927 | 48.467 | 67.429 | 1.00 | 17.46 | D | C |
| ATOM | 3508 | CD1 | TYR | D | 549 | 27.832 | 49.588 | 68.255 | 1.00 | 17.13 | D | C |
| ATOM | 3509 | CE1 | TYR | D | 549 | 27.792 | 49.464 | 69.645 | 1.00 | 17.91 | D | C |
| ATOM | 3510 | CD2 | TYR | D | 549 | 27.971 | 47.207 | 68.033 | 1.00 | 15.30 | D | C |
| ATOM | 3511 | CE2 | TYR | D | 549 | 27.932 | 47.069 | 69.412 | 1.00 | 15.09 | D | C |
| ATOM | 3512 | CZ | TYR | D | 549 | 27.846 | 48.202 | 70.218 | 1.00 | 17.69 | D | C |
| ATOM | 3513 | OH | TYR | D | 549 | 27.858 | 48.087 | 71.591 | 1.00 | 16.47 | D | O |
| ATOM | 3514 | C | TYR | D | 549 | 30.369 | 47.734 | 66.094 | 1.00 | 17.71 | D | C |
| ATOM | 3515 | O | TYR | D | 549 | 31.176 | 48.058 | 66.971 | 1.00 | 17.82 | D | O |
| ATOM | 3516 | N | ALA | D | 550 | 30.210 | 46.473 | 65.667 | 1.00 | 18.42 | D | N |
| ATOM | 3517 | CA | ALA | D | 550 | 30.957 | 45.333 | 66.218 | 1.00 | 17.31 | D | C |
| ATOM | 3518 | CB | ALA | D | 550 | 30.602 | 44.057 | 65.467 | 1.00 | 14.28 | D | C |
| ATOM | 3519 | C | ALA | D | 550 | 32.458 | 45.539 | 66.202 | 1.00 | 18.18 | D | C |
| ATOM | 3520 | O | ALA | D | 550 | 33.132 | 45.288 | 67.197 | 1.00 | 19.79 | D | O |
| ATOM | 3521 | N | ASN | D | 551 | 32.987 | 46.000 | 65.073 | 1.00 | 17.66 | D | N |
| ATOM | 3522 | CA | ASN | D | 551 | 34.421 | 46.234 | 64.964 | 1.00 | 16.09 | D | C |
| ATOM | 3523 | CB | ASN | D | 551 | 34.823 | 46.347 | 63.487 | 1.00 | 15.53 | D | C |
| ATOM | 3524 | CG | ASN | D | 551 | 34.944 | 44.986 | 62.825 | 1.00 | 13.14 | D | C |
| ATOM | 3525 | OD1 | ASN | D | 551 | 34.005 | 44.508 | 62.190 | 1.00 | 14.52 | D | O |
| ATOM | 3526 | ND2 | ASN | D | 551 | 36.092 | 44.349 | 62.986 | 1.00 | 9.73 | D | N |
| ATOM | 3527 | C | ASN | D | 551 | 34.864 | 47.469 | 65.731 | 1.00 | 15.16 | D | C |
| ATOM | 3528 | O | ASN | D | 551 | 35.940 | 47.491 | 66.320 | 1.00 | 14.27 | D | O |
| ATOM | 3529 | N | ILE | D | 552 | 34.029 | 48.499 | 65.739 | 1.00 | 14.27 | D | N |
| ATOM | 3530 | CA | ILE | D | 552 | 34.392 | 49.714 | 66.448 | 1.00 | 16.29 | D | C |
| ATOM | 3531 | CB | ILE | D | 552 | 33.412 | 50.881 | 66.093 | 1.00 | 15.30 | D | C |
| ATOM | 3532 | CG2 | ILE | D | 552 | 33.551 | 52.037 | 67.101 | 1.00 | 10.02 | D | C |
| ATOM | 3533 | CG1 | ILE | D | 552 | 33.720 | 51.373 | 64.661 | 1.00 | 12.85 | D | C |
| ATOM | 3534 | CD1 | ILE | D | 552 | 32.688 | 52.301 | 64.062 | 1.00 | 8.79 | D | C |
| ATOM | 3535 | C | ILE | D | 552 | 34.411 | 49.436 | 67.952 | 1.00 | 17.64 | D | C |
| ATOM | 3536 | O | ILE | D | 552 | 35.237 | 49.979 | 68.683 | 1.00 | 18.80 | D | O |
| ATOM | 3537 | N | MET | D | 553 | 33.511 | 48.573 | 68.411 | 1.00 | 19.01 | D | N |
| ATOM | 3538 | CA | MET | D | 553 | 33.461 | 48.237 | 69.827 | 1.00 | 20.65 | D | C |
| ATOM | 3539 | CB | MET | D | 553 | 32.300 | 47.293 | 70.110 | 1.00 | 20.35 | D | C |
| ATOM | 3540 | CG | MET | D | 553 | 32.521 | 46.459 | 71.359 | 1.00 | 24.75 | D | C |
| ATOM | 3541 | SD | MET | D | 553 | 31.140 | 45.415 | 71.689 | 1.00 | 27.83 | D | S |
| ATOM | 3542 | CE | MET | D | 553 | 31.772 | 44.461 | 73.096 | 1.00 | 29.11 | D | C |
| ATOM | 3543 | C | MET | D | 553 | 34.767 | 47.580 | 70.286 | 1.00 | 19.52 | D | C |
| ATOM | 3544 | O | MET | D | 553 | 35.355 | 47.997 | 71.286 | 1.00 | 20.48 | D | O |
| ATOM | 3545 | N | VAL | D | 554 | 35.205 | 46.553 | 69.556 | 1.00 | 18.42 | D | N |
| ATOM | 3546 | CA | VAL | D | 554 | 36.437 | 45.828 | 69.882 | 1.00 | 16.06 | D | C |
| ATOM | 3547 | CB | VAL | D | 554 | 36.628 | 44.579 | 68.946 | 1.00 | 15.83 | D | C |
| ATOM | 3548 | CG1 | VAL | D | 554 | 37.893 | 43.796 | 69.336 | 1.00 | 14.10 | D | C |
| ATOM | 3549 | CG2 | VAL | D | 554 | 35.408 | 43.659 | 69.035 | 1.00 | 11.43 | D | C |
| ATOM | 3550 | C | VAL | D | 554 | 37.631 | 46.765 | 69.746 | 1.00 | 17.00 | D | C |
| ATOM | 3551 | O | VAL | D | 554 | 38.536 | 46.761 | 70.578 | 1.00 | 18.02 | D | O |
| ATOM | 3552 | N | LEU | D | 555 | 37.631 | 47.582 | 68.697 | 1.00 | 16.14 | D | N |
| ATOM | 3553 | CA | LEU | D | 555 | 38.732 | 48.503 | 68.477 | 1.00 | 14.86 | D | C |
| ATOM | 3554 | CB | LEU | D | 555 | 38.528 | 49.253 | 67.153 | 1.00 | 14.31 | D | C |
| ATOM | 3555 | CG | LEU | D | 555 | 39.590 | 50.289 | 66.752 | 1.00 | 15.77 | D | C |
| ATOM | 3556 | CD1 | LEU | D | 555 | 40.961 | 49.637 | 66.582 | 1.00 | 12.17 | D | C |
| ATOM | 3557 | CD2 | LEU | D | 555 | 39.165 | 50.950 | 65.450 | 1.00 | 16.06 | D | C |
| ATOM | 3558 | C | LEU | D | 555 | 38.842 | 49.494 | 69.637 | 1.00 | 15.57 | D | C |
| ATOM | 3559 | O | LEU | D | 555 | 39.936 | 49.777 | 70.126 | 1.00 | 13.57 | D | O |
| ATOM | 3560 | N | ASN | D | 556 | 37.702 | 50.022 | 70.074 | 1.00 | 16.03 | D | N |
| ATOM | 3561 | CA | ASN | D | 556 | 37.686 | 50.987 | 71.164 | 1.00 | 17.93 | D | C |
| ATOM | 3562 | CB | ASN | D | 556 | 36.284 | 51.564 | 71.321 | 1.00 | 16.65 | D | C |
| ATOM | 3563 | CG | ASN | D | 556 | 35.979 | 52.642 | 70.287 | 1.00 | 16.10 | D | C |
| ATOM | 3564 | OD1 | ASN | D | 556 | 36.878 | 53.137 | 69.604 | 1.00 | 11.84 | D | O |
| ATOM | 3565 | ND2 | ASN | D | 556 | 34.707 | 53.010 | 70.174 | 1.00 | 11.10 | D | N |
| ATOM | 3566 | C | ASN | D | 556 | 38.149 | 50.363 | 72.482 | 1.00 | 19.36 | D | C |
| ATOM | 3567 | O | ASN | D | 556 | 38.818 | 51.016 | 73.298 | 1.00 | 16.13 | D | O |
| ATOM | 3568 | N | SER | D | 557 | 37.787 | 49.100 | 72.681 | 1.00 | 18.11 | D | N |
| ATOM | 3569 | CA | SER | D | 557 | 38.186 | 48.376 | 73.882 | 1.00 | 21.81 | D | C |
| ATOM | 3570 | CB | SER | D | 557 | 37.597 | 46.969 | 73.873 | 1.00 | 20.10 | D | C |
| ATOM | 3571 | OG | SER | D | 557 | 36.182 | 47.017 | 73.894 | 1.00 | 25.28 | D | O |
| ATOM | 3572 | C | SER | D | 557 | 39.702 | 48.273 | 73.908 | 1.00 | 21.20 | D | C |
| ATOM | 3573 | O | SER | D | 557 | 40.350 | 48.540 | 74.921 | 1.00 | 23.61 | D | O |
| ATOM | 3574 | N | LEU | D | 558 | 40.262 | 47.879 | 72.778 | 1.00 | 19.71 | D | N |
| ATOM | 3575 | CA | LEU | D | 558 | 41.691 | 47.732 | 72.677 | 1.00 | 21.52 | D | C |
| ATOM | 3576 | CB | LEU | D | 558 | 42.047 | 47.112 | 71.324 | 1.00 | 23.68 | D | C |
| ATOM | 3577 | CG | LEU | D | 558 | 43.535 | 47.011 | 70.984 | 1.00 | 29.45 | D | C |
| ATOM | 3578 | CD1 | LEU | D | 558 | 44.227 | 46.060 | 71.958 | 1.00 | 28.17 | D | C |
| ATOM | 3579 | CD2 | LEU | D | 558 | 43.695 | 46.507 | 69.556 | 1.00 | 29.59 | D | C |
| ATOM | 3580 | C | LEU | D | 558 | 42.410 | 49.058 | 72.862 | 1.00 | 20.93 | D | C |
| ATOM | 3581 | O | LEU | D | 558 | 43.364 | 49.143 | 73.628 | 1.00 | 22.56 | D | O |
| ATOM | 3582 | N | ARG | D | 559 | 41.944 | 50.099 | 72.184 | 1.00 | 21.01 | D | N |
| ATOM | 3583 | CA | ARG | D | 559 | 42.596 | 51.400 | 72.271 | 1.00 | 20.47 | D | C |
| ATOM | 3584 | CB | ARG | D | 559 | 42.056 | 52.337 | 71.179 | 1.00 | 18.85 | D | C |
| ATOM | 3585 | CG | ARG | D | 559 | 42.653 | 52.062 | 69.781 | 1.00 | 16.71 | D | C |
| ATOM | 3586 | CD | ARG | D | 559 | 42.170 | 53.053 | 68.733 | 1.00 | 14.44 | D | C |
| ATOM | 3587 | NE | ARG | D | 559 | 42.922 | 54.314 | 68.710 | 1.00 | 16.83 | D | N |
| ATOM | 3588 | CZ | ARG | D | 559 | 44.081 | 54.503 | 68.079 | 1.00 | 13.53 | D | C |
| ATOM | 3589 | NH1 | ARG | D | 559 | 44.652 | 53.514 | 67.404 | 1.00 | 15.94 | D | N |
| ATOM | 3590 | NH2 | ARG | D | 559 | 44.661 | 55.689 | 68.102 | 1.00 | 11.81 | D | N |
| ATOM | 3591 | C | ARG | D | 559 | 42.479 | 52.051 | 73.641 | 1.00 | 22.26 | D | C |
| ATOM | 3592 | O | ARG | D | 559 | 43.389 | 52.766 | 74.077 | 1.00 | 22.78 | D | O |
| ATOM | 3593 | N | LYS | D | 560 | 41.355 | 51.818 | 74.313 | 1.00 | 22.62 | D | N |
| ATOM | 3594 | CA | LYS | D | 560 | 41.133 | 52.376 | 75.644 | 1.00 | 25.90 | D | C |
| ATOM | 3595 | CB | LYS | D | 560 | 39.749 | 51.960 | 76.170 | 1.00 | 25.12 | D | C |
| ATOM | 3596 | CG | LYS | D | 560 | 39.457 | 52.353 | 77.618 | 1.00 | 29.26 | D | C |
| ATOM | 3597 | CD | LYS | D | 560 | 38.985 | 53.802 | 77.732 | 1.00 | 34.08 | D | C |
| ATOM | 3598 | CE | LYS | D | 560 | 38.492 | 54.149 | 79.146 | 1.00 | 38.15 | D | C |
| ATOM | 3599 | NZ | LYS | D | 560 | 37.574 | 55.342 | 79.187 | 1.00 | 33.03 | D | N |
| ATOM | 3600 | C | LYS | D | 560 | 42.232 | 51.834 | 76.559 | 1.00 | 26.56 | D | C |
| ATOM | 3601 | O | LYS | D | 560 | 42.907 | 52.589 | 77.261 | 1.00 | 28.48 | D | O |
| ATOM | 3602 | N | GLU | D | 561 | 42.415 | 50.519 | 76.522 | 1.00 | 28.78 | D | N |
| ATOM | 3603 | CA | GLU | D | 561 | 43.428 | 49.852 | 77.324 | 1.00 | 32.72 | D | C |
| ATOM | 3604 | CB | GLU | D | 561 | 43.338 | 48.348 | 77.121 | 1.00 | 37.20 | D | C |
| ATOM | 3605 | CG | GLU | D | 561 | 42.492 | 47.645 | 78.159 | 1.00 | 47.26 | D | C |
| ATOM | 3606 | CD | GLU | D | 561 | 42.321 | 46.167 | 77.841 | 1.00 | 55.44 | D | C |
| ATOM | 3607 | OE1 | GLU | D | 561 | 43.321 | 45.521 | 77.437 | 1.00 | 58.92 | D | O |
| ATOM | 3608 | OE2 | GLU | D | 561 | 41.187 | 45.649 | 77.990 | 1.00 | 59.07 | D | O |
| ATOM | 3609 | C | GLU | D | 561 | 44.848 | 50.317 | 77.018 | 1.00 | 32.03 | D | C |
| ATOM | 3610 | O | GLU | D | 561 | 45.704 | 50.307 | 77.910 | 1.00 | 34.55 | D | O |
| ATOM | 3611 | N | ARG | D | 562 | 45.104 | 50.715 | 75.770 | 1.00 | 27.89 | D | N |
| ATOM | 3612 | CA | ARG | D | 562 | 46.431 | 51.185 | 75.373 | 1.00 | 23.86 | D | C |
| ATOM | 3613 | CB | ARG | D | 562 | 46.630 | 51.030 | 73.859 | 1.00 | 23.59 | D | C |
| ATOM | 3614 | CG | ARG | D | 562 | 46.669 | 49.573 | 73.371 | 1.00 | 25.15 | D | C |
| ATOM | 3615 | CD | ARG | D | 562 | 47.848 | 49.296 | 72.437 | 1.00 | 27.01 | D | C |
| ATOM | 3616 | NE | ARG | D | 562 | 49.147 | 49.365 | 73.112 | 1.00 | 29.65 | D | N |
| ATOM | 3617 | CZ | ARG | D | 562 | 50.325 | 49.364 | 72.485 | 1.00 | 30.80 | D | C |
| ATOM | 3618 | NH1 | ARG | D | 562 | 50.393 | 49.296 | 71.159 | 1.00 | 28.31 | D | N |
| ATOM | 3619 | NH2 | ARG | D | 562 | 51.444 | 49.437 | 73.189 | 1.00 | 32.01 | D | N |
| ATOM | 3620 | C | ARG | D | 562 | 46.623 | 52.645 | 75.760 | 1.00 | 23.05 | D | C |
| ATOM | 3621 | O | ARG | D | 562 | 47.715 | 53.202 | 75.640 | 1.00 | 22.44 | D | O |
| ATOM | 3622 | N | GLY | D | 563 | 45.556 | 53.268 | 76.237 | 1.00 | 22.10 | D | N |
| ATOM | 3623 | CA | GLY | D | 563 | 45.652 | 54.663 | 76.609 | 1.00 | 21.80 | D | C |
| ATOM | 3624 | C | GLY | D | 563 | 45.505 | 55.544 | 75.381 | 1.00 | 22.62 | D | C |
| ATOM | 3625 | O | GLY | D | 563 | 45.865 | 56.727 | 75.409 | 1.00 | 22.20 | D | O |
| ATOM | 3626 | N | MET | D | 564 | 44.964 | 54.973 | 74.303 | 1.00 | 20.66 | D | N |
| ATOM | 3627 | CA | MET | D | 564 | 44.785 | 55.707 | 73.055 | 1.00 | 21.31 | D | C |
| ATOM | 3628 | CB | MET | D | 564 | 45.115 | 54.812 | 71.858 | 1.00 | 20.76 | D | C |
| ATOM | 3629 | CG | MET | D | 564 | 46.586 | 54.456 | 71.694 | 1.00 | 24.14 | D | C |
| ATOM | 3630 | SD | MET | D | 564 | 46.798 | 53.032 | 70.607 | 1.00 | 23.45 | D | S |
| ATOM | 3631 | CE | MET | D | 564 | 48.508 | 53.204 | 70.136 | 1.00 | 24.36 | D | C |
| ATOM | 3632 | C | MET | D | 564 | 43.359 | 56.225 | 72.916 | 1.00 | 21.69 | D | C |
| ATOM | 3633 | O | MET | D | 564 | 42.469 | 55.838 | 73.681 | 1.00 | 24.75 | D | O |
| ATOM | 3634 | N | ASN | D | 565 | 43.141 | 57.099 | 71.933 | 1.00 | 21.98 | D | N |
| ATOM | 3635 | CA | ASN | D | 565 | 41.820 | 57.668 | 71.695 | 1.00 | 17.55 | D | C |
| ATOM | 3636 | CB | ASN | D | 565 | 41.914 | 58.880 | 70.756 | 1.00 | 17.73 | D | C |
| ATOM | 3637 | CG | ASN | D | 565 | 42.516 | 58.539 | 69.401 | 1.00 | 17.80 | D | C |
| ATOM | 3638 | OD1 | ASN | D | 565 | 43.644 | 58.062 | 69.317 | 1.00 | 16.84 | D | O |
| ATOM | 3639 | ND2 | ASN | D | 565 | 41.759 | 58.791 | 68.330 | 1.00 | 14.96 | D | N |
| ATOM | 3640 | C | ASN | D | 565 | 40.896 | 56.612 | 71.110 | 1.00 | 16.84 | D | C |
| ATOM | 3641 | O | ASN | D | 565 | 41.357 | 55.661 | 70.488 | 1.00 | 16.06 | D | O |
| ATOM | 3642 | N | THR | D | 566 | 39.595 | 56.768 | 71.347 | 1.00 | 15.33 | D | N |
| ATOM | 3643 | CA | THR | D | 566 | 38.599 | 55.839 | 70.846 | 1.00 | 15.40 | D | C |
| ATOM | 3644 | CB | THR | D | 566 | 37.737 | 55.248 | 72.012 | 1.00 | 17.84 | D | C |
| ATOM | 3645 | OG1 | THR | D | 566 | 37.032 | 56.300 | 72.678 | 1.00 | 20.10 | D | O |
| ATOM | 3646 | CG2 | THR | D | 566 | 38.623 | 54.538 | 73.028 | 1.00 | 17.67 | D | C |
| ATOM | 3647 | C | THR | D | 566 | 37.706 | 56.573 | 69.828 | 1.00 | 14.79 | D | C |
| ATOM | 3648 | O | THR | D | 566 | 37.798 | 57.794 | 69.674 | 1.00 | 14.47 | D | O |
| ATOM | 3649 | N | PHE | D | 567 | 36.826 | 55.837 | 69.153 | 1.00 | 13.23 | D | N |
| ATOM | 3650 | CA | PHE | D | 567 | 35.986 | 56.425 | 68.113 | 1.00 | 13.39 | D | C |
| ATOM | 3651 | CB | PHE | D | 567 | 36.341 | 55.806 | 66.750 | 1.00 | 11.92 | D | C |
| ATOM | 3652 | CG | PHE | D | 567 | 37.818 | 55.708 | 66.494 | 1.00 | 10.60 | D | C |
| ATOM | 3653 | CD1 | PHE | D | 567 | 38.563 | 56.844 | 66.193 | 1.00 | 11.58 | D | C |
| ATOM | 3654 | CD2 | PHE | D | 567 | 38.470 | 54.489 | 66.573 | 1.00 | 12.10 | D | C |
| ATOM | 3655 | CE1 | PHE | D | 567 | 39.939 | 56.774 | 65.978 | 1.00 | 9.17 | D | C |
| ATOM | 3656 | CE2 | PHE | D | 567 | 39.849 | 54.409 | 66.359 | 1.00 | 11.50 | D | C |
| ATOM | 3657 | CZ | PHE | D | 567 | 40.582 | 55.560 | 66.061 | 1.00 | 6.88 | D | C |
| ATOM | 3658 | C | PHE | D | 567 | 34.486 | 56.317 | 68.282 | 1.00 | 10.64 | D | C |
| ATOM | 3659 | O | PHE | D | 567 | 33.982 | 55.338 | 68.811 | 1.00 | 10.55 | D | O |
| ATOM | 3660 | N | LEU | D | 568 | 33.783 | 57.332 | 67.790 | 1.00 | 9.94 | D | N |
| ATOM | 3661 | CA | LEU | D | 568 | 32.326 | 57.359 | 67.828 | 1.00 | 11.76 | D | C |
| ATOM | 3662 | CB | LEU | D | 568 | 31.830 | 58.786 | 68.037 | 1.00 | 11.38 | D | C |
| ATOM | 3663 | CG | LEU | D | 568 | 32.203 | 59.483 | 69.347 | 1.00 | 12.43 | D | C |
| ATOM | 3664 | CD1 | LEU | D | 568 | 31.431 | 60.799 | 69.437 | 1.00 | 12.81 | D | C |
| ATOM | 3665 | CD2 | LEU | D | 568 | 31.861 | 58.581 | 70.535 | 1.00 | 8.17 | D | C |
| ATOM | 3666 | C | LEU | D | 568 | 31.771 | 56.846 | 66.498 | 1.00 | 13.02 | D | C |
| ATOM | 3667 | O | LEU | D | 568 | 32.416 | 56.968 | 65.458 | 1.00 | 15.72 | D | O |
| ATOM | 3668 | N | PHE | D | 569 | 30.590 | 56.242 | 66.540 | 1.00 | 12.48 | D | N |
| ATOM | 3669 | CA | PHE | D | 569 | 29.931 | 55.766 | 65.323 | 1.00 | 14.07 | D | C |
| ATOM | 3670 | CB | PHE | D | 569 | 29.369 | 54.347 | 65.514 | 1.00 | 11.68 | D | C |
| ATOM | 3671 | CG | PHE | D | 569 | 28.701 | 53.781 | 64.282 | 1.00 | 10.47 | D | C |
| ATOM | 3672 | CD1 | PHE | D | 569 | 29.272 | 53.952 | 63.016 | 1.00 | 7.38 | D | C |
| ATOM | 3673 | CD2 | PHE | D | 569 | 27.516 | 53.060 | 64.394 | 1.00 | 9.75 | D | C |
| ATOM | 3674 | CE1 | PHE | D | 569 | 28.678 | 53.407 | 61.879 | 1.00 | 8.13 | D | C |
| ATOM | 3675 | CE2 | PHE | D | 569 | 26.903 | 52.504 | 63.268 | 1.00 | 11.99 | D | C |
| ATOM | 3676 | CZ | PHE | D | 569 | 27.488 | 52.677 | 61.999 | 1.00 | 12.42 | D | C |
| ATOM | 3677 | C | PHE | D | 569 | 28.792 | 56.768 | 65.106 | 1.00 | 13.46 | D | C |
| ATOM | 3678 | O | PHE | D | 569 | 27.865 | 56.847 | 65.930 | 1.00 | 15.13 | D | O |
| ATOM | 3679 | N | ARG | D | 570 | 28.885 | 57.541 | 64.021 | 1.00 | 13.46 | D | N |
| ATOM | 3680 | CA | ARG | D | 570 | 27.900 | 58.586 | 63.675 | 1.00 | 12.65 | D | C |
| ATOM | 3681 | CB | ARG | D | 570 | 28.500 | 59.965 | 63.959 | 1.00 | 10.02 | D | C |
| ATOM | 3682 | CG | ARG | D | 570 | 29.249 | 60.028 | 65.285 | 1.00 | 8.68 | D | C |
| ATOM | 3683 | CD | ARG | D | 570 | 30.092 | 61.279 | 65.426 | 1.00 | 8.09 | D | C |
| ATOM | 3684 | NE | ARG | D | 570 | 29.359 | 62.476 | 65.026 | 1.00 | 11.75 | D | N |
| ATOM | 3685 | CZ | ARG | D | 570 | 29.879 | 63.704 | 65.000 | 1.00 | 10.78 | D | C |
| ATOM | 3686 | NH1 | ARG | D | 570 | 31.137 | 63.919 | 65.347 | 1.00 | 11.48 | D | N |
| ATOM | 3687 | NH2 | ARG | D | 570 | 29.148 | 64.723 | 64.585 | 1.00 | 11.41 | D | N |
| ATOM | 3688 | C | ARG | D | 570 | 27.474 | 58.506 | 62.207 | 1.00 | 14.05 | D | C |
| ATOM | 3689 | O | ARG | D | 570 | 27.871 | 59.332 | 61.381 | 1.00 | 12.62 | D | O |
| ATOM | 3690 | N | PRO | D | 571 | 26.609 | 57.533 | 61.877 | 1.00 | 13.13 | D | N |
| ATOM | 3691 | CD | PRO | D | 571 | 25.981 | 56.569 | 62.802 | 1.00 | 10.22 | D | C |
| ATOM | 3692 | CA | PRO | D | 571 | 26.135 | 57.336 | 60.506 | 1.00 | 11.31 | D | C |
| ATOM | 3693 | CB | PRO | D | 571 | 25.634 | 55.903 | 60.522 | 1.00 | 9.69 | D | C |
| ATOM | 3694 | CG | PRO | D | 571 | 25.027 | 55.794 | 61.900 | 1.00 | 8.91 | D | C |
| ATOM | 3695 | C | PRO | D | 571 | 25.024 | 58.271 | 60.055 | 1.00 | 14.14 | D | C |
| ATOM | 3696 | O | PRO | D | 571 | 24.364 | 58.920 | 60.872 | 1.00 | 11.84 | D | O |
| ATOM | 3697 | N | HIS | D | 572 | 24.842 | 58.317 | 58.732 | 1.00 | 12.24 | D | N |
| ATOM | 3698 | CA | HIS | D | 572 | 23.776 | 59.081 | 58.109 | 1.00 | 12.92 | D | C |
| ATOM | 3699 | CB | HIS | D | 572 | 23.993 | 59.154 | 56.590 | 1.00 | 10.83 | D | C |
| ATOM | 3700 | CG | HIS | D | 572 | 24.912 | 60.258 | 56.164 | 1.00 | 9.54 | D | C |
| ATOM | 3701 | CD2 | HIS | D | 572 | 24.760 | 61.232 | 55.236 | 1.00 | 8.50 | D | C |
| ATOM | 3702 | ND1 | HIS | D | 572 | 26.148 | 60.466 | 56.743 | 1.00 | 7.34 | D | N |
| ATOM | 3703 | CE1 | HIS | D | 572 | 26.715 | 61.523 | 56.190 | 1.00 | 9.80 | D | C |
| ATOM | 3704 | NE2 | HIS | D | 572 | 25.894 | 62.006 | 55.272 | 1.00 | 11.29 | D | N |
| ATOM | 3705 | C | HIS | D | 572 | 22.597 | 58.163 | 58.424 | 1.00 | 11.67 | D | C |
| ATOM | 3706 | O | HIS | D | 572 | 22.693 | 56.946 | 58.242 | 1.00 | 11.00 | D | O |
| ATOM | 3707 | N | CYS | D | 573 | 21.493 | 58.710 | 58.901 | 1.00 | 10.54 | D | N |
| ATOM | 3708 | CA | CYS | D | 573 | 20.377 | 57.846 | 59.249 | 1.00 | 10.95 | D | C |
| ATOM | 3709 | CB | CYS | D | 573 | 20.594 | 57.266 | 60.650 | 1.00 | 10.85 | D | C |
| ATOM | 3710 | SG | CYS | D | 573 | 19.393 | 55.993 | 61.156 | 1.00 | 14.01 | D | S |
| ATOM | 3711 | C | CYS | D | 573 | 19.065 | 58.587 | 59.215 | 1.00 | 11.32 | D | C |
| ATOM | 3712 | O | CYS | D | 573 | 18.975 | 59.718 | 59.701 | 1.00 | 12.21 | D | O |
| ATOM | 3713 | N | GLY | D | 574 | 18.061 | 57.951 | 58.617 | 1.00 | 9.37 | D | N |
| ATOM | 3714 | CA | GLY | D | 574 | 16.738 | 58.534 | 58.544 | 1.00 | 10.87 | D | C |
| ATOM | 3715 | C | GLY | D | 574 | 16.480 | 59.575 | 57.478 | 1.00 | 12.61 | D | C |
| ATOM | 3716 | O | GLY | D | 574 | 15.448 | 60.236 | 57.509 | 1.00 | 12.89 | D | O |
| ATOM | 3717 | N | GLU | D | 575 | 17.407 | 59.746 | 56.544 | 1.00 | 14.44 | D | N |
| ATOM | 3718 | CA | GLU | D | 575 | 17.204 | 60.719 | 55.481 | 1.00 | 13.78 | D | C |
| ATOM | 3719 | CB | GLU | D | 575 | 18.460 | 60.888 | 54.651 | 1.00 | 15.25 | D | C |
| ATOM | 3720 | CG | GLU | D | 575 | 18.308 | 61.953 | 53.596 | 1.00 | 16.02 | D | C |
| ATOM | 3721 | CD | GLU | D | 575 | 19.586 | 62.176 | 52.840 | 1.00 | 17.69 | D | C |
| ATOM | 3722 | OE1 | GLU | D | 575 | 19.808 | 63.310 | 52.361 | 1.00 | 22.06 | D | O |
| ATOM | 3723 | OE2 | GLU | D | 575 | 20.374 | 61.216 | 52.730 | 1.00 | 16.72 | D | O |
| ATOM | 3724 | C | GLU | D | 575 | 16.114 | 60.165 | 54.595 | 1.00 | 17.23 | D | C |
| ATOM | 3725 | O | GLU | D | 575 | 15.331 | 60.909 | 54.013 | 1.00 | 18.07 | D | O |
| ATOM | 3726 | N | VAL | D | 576 | 16.091 | 58.840 | 54.492 | 1.00 | 19.65 | D | N |
| ATOM | 3727 | CA | VAL | D | 576 | 15.096 | 58.112 | 53.713 | 1.00 | 21.44 | D | C |
| ATOM | 3728 | CB | VAL | D | 576 | 15.248 | 58.318 | 52.201 | 1.00 | 24.21 | D | C |
| ATOM | 3729 | CG1 | VAL | D | 576 | 14.470 | 59.539 | 51.774 | 1.00 | 31.07 | D | C |
| ATOM | 3730 | CG2 | VAL | D | 576 | 16.705 | 58.441 | 51.822 | 1.00 | 30.08 | D | C |
| ATOM | 3731 | C | VAL | D | 576 | 15.281 | 56.640 | 53.992 | 1.00 | 20.03 | D | C |
| ATOM | 3732 | O | VAL | D | 576 | 16.111 | 56.264 | 54.818 | 1.00 | 19.15 | D | O |
| ATOM | 3733 | N | GLY | D | 577 | 14.513 | 55.807 | 53.300 | 1.00 | 16.68 | D | N |
| ATOM | 3734 | CA | GLY | D | 577 | 14.629 | 54.382 | 53.523 | 1.00 | 16.39 | D | C |
| ATOM | 3735 | C | GLY | D | 577 | 13.717 | 53.940 | 54.651 | 1.00 | 16.40 | D | C |
| ATOM | 3736 | O | GLY | D | 577 | 12.877 | 54.716 | 55.117 | 1.00 | 14.87 | D | O |
| ATOM | 3737 | N | ALA | D | 578 | 13.892 | 52.695 | 55.091 | 1.00 | 17.31 | D | N |
| ATOM | 3738 | CA | ALA | D | 578 | 13.089 | 52.093 | 56.161 | 1.00 | 18.43 | D | C |
| ATOM | 3739 | CB | ALA | D | 578 | 13.363 | 50.592 | 56.215 | 1.00 | 14.71 | D | C |
| ATOM | 3740 | C | ALA | D | 578 | 13.307 | 52.709 | 57.550 | 1.00 | 18.88 | D | C |
| ATOM | 3741 | O | ALA | D | 578 | 14.379 | 53.236 | 57.857 | 1.00 | 17.82 | D | O |
| ATOM | 3742 | N | LEU | D | 579 | 12.278 | 52.629 | 58.387 | 1.00 | 21.26 | D | N |
| ATOM | 3743 | CA | LEU | D | 579 | 12.352 | 53.162 | 59.748 | 1.00 | 23.45 | D | C |
| ATOM | 3744 | CB | LEU | D | 579 | 10.988 | 53.071 | 60.431 | 1.00 | 24.52 | D | C |
| ATOM | 3745 | CG | LEU | D | 579 | 9.998 | 54.176 | 60.106 | 1.00 | 26.08 | D | C |
| ATOM | 3746 | CD1 | LEU | D | 579 | 8.698 | 53.876 | 60.823 | 1.00 | 29.29 | D | C |
| ATOM | 3747 | CD2 | LEU | D | 579 | 10.562 | 55.528 | 60.527 | 1.00 | 31.61 | D | C |
| ATOM | 3748 | C | LEU | D | 579 | 13.350 | 52.348 | 60.554 | 1.00 | 23.33 | D | C |
| ATOM | 3749 | O | LEU | D | 579 | 13.982 | 52.857 | 61.481 | 1.00 | 26.78 | D | O |
| ATOM | 3750 | N | THR | D | 580 | 13.479 | 51.074 | 60.200 | 1.00 | 21.98 | D | N |
| ATOM | 3751 | CA | THR | D | 580 | 14.394 | 50.202 | 60.895 | 1.00 | 21.04 | D | C |
| ATOM | 3752 | CB | THR | D | 580 | 14.413 | 48.798 | 60.257 | 1.00 | 23.05 | D | C |
| ATOM | 3753 | OG1 | THR | D | 580 | 14.806 | 48.890 | 58.884 | 1.00 | 22.65 | D | O |
| ATOM | 3754 | CG2 | THR | D | 580 | 13.037 | 48.177 | 60.327 | 1.00 | 22.04 | D | C |
| ATOM | 3755 | C | THR | D | 580 | 15.802 | 50.786 | 60.900 | 1.00 | 20.63 | D | C |
| ATOM | 3756 | O | THR | D | 580 | 16.645 | 50.341 | 61.665 | 1.00 | 21.74 | D | O |
| ATOM | 3757 | N | HIS | D | 581 | 16.064 | 51.763 | 60.034 | 1.00 | 18.45 | D | N |
| ATOM | 3758 | CA | HIS | D | 581 | 17.381 | 52.389 | 60.003 | 1.00 | 17.65 | D | C |
| ATOM | 3759 | CB | HIS | D | 581 | 17.511 | 53.376 | 58.844 | 1.00 | 17.82 | D | C |
| ATOM | 3760 | CG | HIS | D | 581 | 17.591 | 52.728 | 57.501 | 1.00 | 16.64 | D | C |
| ATOM | 3761 | CD2 | HIS | D | 581 | 17.402 | 51.446 | 57.116 | 1.00 | 16.40 | D | C |
| ATOM | 3762 | ND1 | HIS | D | 581 | 17.841 | 53.443 | 56.353 | 1.00 | 17.54 | D | N |
| ATOM | 3763 | CE1 | HIS | D | 581 | 17.801 | 52.628 | 55.315 | 1.00 | 19.08 | D | C |
| ATOM | 3764 | NE2 | HIS | D | 581 | 17.536 | 51.409 | 55.751 | 1.00 | 19.34 | D | N |
| ATOM | 3765 | C | HIS | D | 581 | 17.580 | 53.164 | 61.293 | 1.00 | 16.30 | D | C |
| ATOM | 3766 | O | HIS | D | 581 | 18.664 | 53.155 | 61.868 | 1.00 | 15.51 | D | O |
| ATOM | 3767 | N | LEU | D | 582 | 16.522 | 53.838 | 61.739 | 1.00 | 14.38 | D | N |
| ATOM | 3768 | CA | LEU | D | 582 | 16.591 | 54.649 | 62.946 | 1.00 | 14.83 | D | C |
| ATOM | 3769 | CB | LEU | D | 582 | 15.416 | 55.629 | 62.957 | 1.00 | 11.86 | D | C |
| ATOM | 3770 | CG | LEU | D | 582 | 15.649 | 56.765 | 61.947 | 1.00 | 11.05 | D | C |
| ATOM | 3771 | CD1 | LEU | D | 582 | 14.332 | 57.390 | 61.546 | 1.00 | 11.54 | D | C |
| ATOM | 3772 | CD2 | LEU | D | 582 | 16.574 | 57.822 | 62.551 | 1.00 | 9.45 | D | C |
| ATOM | 3773 | C | LEU | D | 582 | 16.619 | 53.773 | 64.197 | 1.00 | 14.66 | D | C |
| ATOM | 3774 | O | LEU | D | 582 | 17.218 | 54.115 | 65.214 | 1.00 | 14.67 | D | O |
| ATOM | 3775 | N | MET | D | 583 | 15.979 | 52.620 | 64.101 | 1.00 | 16.64 | D | N |
| ATOM | 3776 | CA | MET | D | 583 | 15.948 | 51.684 | 65.203 | 1.00 | 16.98 | D | C |
| ATOM | 3777 | CB | MET | D | 583 | 15.011 | 50.535 | 64.852 | 1.00 | 19.50 | D | C |
| ATOM | 3778 | CG | MET | D | 583 | 14.835 | 49.525 | 65.943 | 1.00 | 26.31 | D | C |
| ATOM | 3779 | SD | MET | D | 583 | 15.622 | 47.992 | 65.462 | 1.00 | 39.55 | D | S |
| ATOM | 3780 | CE | MET | D | 583 | 17.226 | 48.233 | 66.034 | 1.00 | 32.24 | D | C |
| ATOM | 3781 | C | MET | D | 583 | 17.372 | 51.183 | 65.438 | 1.00 | 18.12 | D | C |
| ATOM | 3782 | O | MET | D | 583 | 17.854 | 51.152 | 66.573 | 1.00 | 18.50 | D | O |
| ATOM | 3783 | N | THR | D | 584 | 18.054 | 50.807 | 64.361 | 1.00 | 13.50 | D | N |
| ATOM | 3784 | CA | THR | D | 584 | 19.420 | 50.307 | 64.441 | 1.00 | 12.80 | D | C |
| ATOM | 3785 | CB | THR | D | 584 | 19.900 | 49.839 | 63.043 | 1.00 | 15.60 | D | C |
| ATOM | 3786 | OG1 | THR | D | 584 | 19.045 | 48.789 | 62.591 | 1.00 | 15.36 | D | O |
| ATOM | 3787 | CG2 | THR | D | 584 | 21.331 | 49.314 | 63.090 | 1.00 | 14.61 | D | C |
| ATOM | 3788 | C | THR | D | 584 | 20.384 | 51.358 | 64.993 | 1.00 | 11.85 | D | C |
| ATOM | 3789 | O | THR | D | 584 | 21.298 | 51.032 | 65.743 | 1.00 | 12.14 | D | O |
| ATOM | 3790 | N | ALA | D | 585 | 20.186 | 52.616 | 64.612 | 1.00 | 10.07 | D | N |
| ATOM | 3791 | CA | ALA | D | 585 | 21.036 | 53.698 | 65.101 | 1.00 | 10.91 | D | C |
| ATOM | 3792 | CB | ALA | D | 585 | 20.730 | 54.993 | 64.350 | 1.00 | 7.85 | D | C |
| ATOM | 3793 | C | ALA | D | 585 | 20.793 | 53.897 | 66.599 | 1.00 | 11.25 | D | C |
| ATOM | 3794 | O | ALA | D | 585 | 21.701 | 54.266 | 67.334 | 1.00 | 10.23 | D | O |
| ATOM | 3795 | N | PHE | D | 586 | 19.554 | 53.675 | 67.036 | 1.00 | 11.90 | D | N |
| ATOM | 3796 | CA | PHE | D | 586 | 19.217 | 53.807 | 68.443 | 1.00 | 12.65 | D | C |
| ATOM | 3797 | CB | PHE | D | 586 | 17.734 | 53.481 | 68.679 | 1.00 | 12.28 | D | C |
| ATOM | 3798 | CG | PHE | D | 586 | 17.310 | 53.562 | 70.141 | 1.00 | 15.04 | D | C |
| ATOM | 3799 | CD1 | PHE | D | 586 | 17.072 | 54.797 | 70.748 | 1.00 | 13.83 | D | C |
| ATOM | 3800 | CD2 | PHE | D | 586 | 17.162 | 52.397 | 70.907 | 1.00 | 14.12 | D | C |
| ATOM | 3801 | CE1 | PHE | D | 586 | 16.696 | 54.875 | 72.090 | 1.00 | 16.68 | D | C |
| ATOM | 3802 | CE2 | PHE | D | 586 | 16.787 | 52.460 | 72.244 | 1.00 | 11.98 | D | C |
| ATOM | 3803 | CZ | PHE | D | 586 | 16.553 | 53.700 | 72.843 | 1.00 | 12.85 | D | C |
| ATOM | 3804 | C | PHE | D | 586 | 20.105 | 52.836 | 69.236 | 1.00 | 14.42 | D | C |
| ATOM | 3805 | O | PHE | D | 586 | 20.594 | 53.174 | 70.314 | 1.00 | 15.36 | D | O |
| ATOM | 3806 | N | MET | D | 587 | 20.333 | 51.649 | 68.677 | 1.00 | 12.29 | D | N |
| ATOM | 3807 | CA | MET | D | 587 | 21.159 | 50.628 | 69.321 | 1.00 | 14.33 | D | C |
| ATOM | 3808 | CB | MET | D | 587 | 20.846 | 49.229 | 68.760 | 1.00 | 11.43 | D | C |
| ATOM | 3809 | CG | MET | D | 587 | 19.433 | 48.732 | 68.937 | 1.00 | 12.81 | D | C |
| ATOM | 3810 | SD | MET | D | 587 | 19.204 | 47.079 | 68.224 | 1.00 | 17.69 | D | S |
| ATOM | 3811 | CE | MET | D | 587 | 20.355 | 46.056 | 69.235 | 1.00 | 11.35 | D | C |
| ATOM | 3812 | C | MET | D | 587 | 22.664 | 50.796 | 69.174 | 1.00 | 15.63 | D | C |
| ATOM | 3813 | O | MET | D | 587 | 23.412 | 50.395 | 70.072 | 1.00 | 18.72 | D | O |
| ATOM | 3814 | N | THR | D | 588 | 23.108 | 51.394 | 68.063 | 1.00 | 13.77 | D | N |
| ATOM | 3815 | CA | THR | D | 588 | 24.540 | 51.466 | 67.745 | 1.00 | 10.92 | D | C |
| ATOM | 3816 | CB | THR | D | 588 | 24.799 | 50.670 | 66.418 | 1.00 | 13.63 | D | C |
| ATOM | 3817 | OG1 | THR | D | 588 | 24.014 | 51.249 | 65.362 | 1.00 | 12.97 | D | O |
| ATOM | 3818 | CG2 | THR | D | 588 | 24.390 | 49.221 | 66.548 | 1.00 | 5.46 | D | C |
| ATOM | 3819 | C | THR | D | 588 | 25.275 | 52.796 | 67.591 | 1.00 | 10.89 | D | C |
| ATOM | 3820 | O | THR | D | 588 | 26.508 | 52.839 | 67.676 | 1.00 | 9.03 | D | O |
| ATOM | 3821 | N | ALA | D | 589 | 24.544 | 53.873 | 67.357 | 1.00 | 10.08 | D | N |
| ATOM | 3822 | CA | ALA | D | 589 | 25.184 | 55.170 | 67.119 | 1.00 | 12.85 | D | C |
| ATOM | 3823 | CB | ALA | D | 589 | 24.542 | 55.820 | 65.858 | 1.00 | 7.76 | D | C |
| ATOM | 3824 | C | ALA | D | 589 | 25.204 | 56.199 | 68.257 | 1.00 | 12.09 | D | C |
| ATOM | 3825 | O | ALA | D | 589 | 24.207 | 56.402 | 68.939 | 1.00 | 13.40 | D | O |
| ATOM | 3826 | N | ASP | D | 590 | 26.341 | 56.869 | 68.430 | 1.00 | 12.69 | D | N |
| ATOM | 3827 | CA | ASP | D | 590 | 26.465 | 57.910 | 69.437 | 1.00 | 14.80 | D | C |
| ATOM | 3828 | CB | ASP | D | 590 | 27.909 | 58.425 | 69.480 | 1.00 | 11.92 | D | C |
| ATOM | 3829 | CG | ASP | D | 590 | 28.095 | 59.571 | 70.469 | 1.00 | 16.41 | D | C |
| ATOM | 3830 | OD1 | ASP | D | 590 | 27.785 | 60.726 | 70.100 | 1.00 | 16.49 | D | O |
| ATOM | 3831 | OD2 | ASP | D | 590 | 28.550 | 59.329 | 71.615 | 1.00 | 14.92 | D | O |
| ATOM | 3832 | C | ASP | D | 590 | 25.489 | 59.044 | 69.038 | 1.00 | 15.88 | D | C |
| ATOM | 3833 | O | ASP | D | 590 | 24.757 | 59.588 | 69.866 | 1.00 | 17.42 | D | O |
| ATOM | 3834 | N | ASN | D | 591 | 25.498 | 59.396 | 67.756 | 1.00 | 15.99 | D | N |
| ATOM | 3835 | CA | ASN | D | 591 | 24.600 | 60.414 | 67.197 | 1.00 | 13.81 | D | C |
| ATOM | 3836 | CB | ASN | D | 591 | 25.097 | 61.847 | 67.489 | 1.00 | 8.26 | D | C |
| ATOM | 3837 | CG | ASN | D | 591 | 26.478 | 62.143 | 66.926 | 1.00 | 12.90 | D | C |
| ATOM | 3838 | OD1 | ASN | D | 591 | 27.479 | 62.083 | 67.651 | 1.00 | 13.16 | D | O |
| ATOM | 3839 | ND2 | ASN | D | 591 | 26.545 | 62.495 | 65.644 | 1.00 | 7.75 | D | N |
| ATOM | 3840 | C | ASN | D | 591 | 24.459 | 60.154 | 65.687 | 1.00 | 12.09 | D | C |
| ATOM | 3841 | O | ASN | D | 591 | 25.161 | 59.305 | 65.128 | 1.00 | 12.01 | D | O |
| ATOM | 3842 | N | ILE | D | 592 | 23.546 | 60.855 | 65.030 | 1.00 | 13.89 | D | N |
| ATOM | 3843 | CA | ILE | D | 592 | 23.328 | 60.636 | 63.595 | 1.00 | 11.41 | D | C |
| ATOM | 3844 | CB | ILE | D | 592 | 21.995 | 59.872 | 63.339 | 1.00 | 6.81 | D | C |
| ATOM | 3845 | CG2 | ILE | D | 592 | 22.002 | 58.532 | 64.029 | 1.00 | 8.05 | D | C |
| ATOM | 3846 | CG1 | ILE | D | 592 | 20.819 | 60.703 | 63.868 | 1.00 | 10.52 | D | C |
| ATOM | 3847 | CD1 | ILE | D | 592 | 19.444 | 60.256 | 63.352 | 1.00 | 5.64 | D | C |
| ATOM | 3848 | C | ILE | D | 592 | 23.238 | 61.942 | 62.818 | 1.00 | 13.02 | D | C |
| ATOM | 3849 | O | ILE | D | 592 | 23.249 | 63.036 | 63.402 | 1.00 | 14.29 | D | O |
| ATOM | 3850 | N | SER | D | 593 | 23.144 | 61.810 | 61.495 | 1.00 | 11.61 | D | N |
| ATOM | 3851 | CA | SER | D | 593 | 22.966 | 62.953 | 60.611 | 1.00 | 10.41 | D | C |
| ATOM | 3852 | CB | SER | D | 593 | 24.128 | 63.057 | 59.623 | 1.00 | 11.05 | D | C |
| ATOM | 3853 | OG | SER | D | 593 | 25.336 | 63.345 | 60.299 | 1.00 | 9.94 | D | O |
| ATOM | 3854 | C | SER | D | 593 | 21.644 | 62.715 | 59.866 | 1.00 | 9.63 | D | C |
| ATOM | 3855 | O | SER | D | 593 | 21.348 | 61.585 | 59.467 | 1.00 | 10.34 | D | O |
| ATOM | 3856 | N | HIS | D | 594 | 20.860 | 63.784 | 59.733 | 1.00 | 8.98 | D | N |
| ATOM | 3857 | CA | HIS | D | 594 | 19.544 | 63.837 | 59.063 | 1.00 | 10.81 | D | C |
| ATOM | 3858 | CB | HIS | D | 594 | 19.462 | 62.913 | 57.829 | 1.00 | 10.29 | D | C |
| ATOM | 3859 | CG | HIS | D | 594 | 20.303 | 63.372 | 56.673 | 1.00 | 9.61 | D | C |
| ATOM | 3860 | CD2 | HIS | D | 594 | 21.371 | 62.800 | 56.068 | 1.00 | 7.40 | D | C |
| ATOM | 3861 | ND1 | HIS | D | 594 | 20.140 | 64.606 | 56.076 | 1.00 | 8.39 | D | N |
| ATOM | 3862 | CE1 | HIS | D | 594 | 21.078 | 64.776 | 55.158 | 1.00 | 5.66 | D | C |
| ATOM | 3863 | NE2 | HIS | D | 594 | 21.837 | 63.695 | 55.133 | 1.00 | 8.70 | D | N |
| ATOM | 3864 | C | HIS | D | 594 | 18.401 | 63.524 | 60.015 | 1.00 | 11.08 | D | C |
| ATOM | 3865 | O | HIS | D | 594 | 17.805 | 64.439 | 60.572 | 1.00 | 10.57 | D | O |
| ATOM | 3866 | N | GLY | D | 595 | 18.089 | 62.244 | 60.181 | 1.00 | 9.82 | D | N |
| ATOM | 3867 | CA | GLY | D | 595 | 17.020 | 61.839 | 61.083 | 1.00 | 11.87 | D | C |
| ATOM | 3868 | C | GLY | D | 595 | 15.596 | 62.248 | 60.734 | 1.00 | 13.93 | D | C |
| ATOM | 3869 | O | GLY | D | 595 | 14.702 | 62.174 | 61.580 | 1.00 | 13.17 | D | O |
| ATOM | 3870 | N | LEU | D | 596 | 15.364 | 62.650 | 59.488 | 1.00 | 13.61 | D | N |
| ATOM | 3871 | CA | LEU | D | 596 | 14.044 | 63.097 | 59.070 | 1.00 | 11.76 | D | C |
| ATOM | 3872 | CB | LEU | D | 596 | 14.087 | 63.519 | 57.593 | 1.00 | 13.43 | D | C |
| ATOM | 3873 | CG | LEU | D | 596 | 15.156 | 64.563 | 57.239 | 1.00 | 15.31 | D | C |
| ATOM | 3874 | CD1 | LEU | D | 596 | 15.359 | 64.644 | 55.731 | 1.00 | 12.67 | D | C |
| ATOM | 3875 | CD2 | LEU | D | 596 | 14.712 | 65.918 | 57.802 | 1.00 | 15.10 | D | C |
| ATOM | 3876 | C | LEU | D | 596 | 12.924 | 62.075 | 59.285 | 1.00 | 11.86 | D | C |
| ATOM | 3877 | O | LEU | D | 596 | 11.817 | 62.429 | 59.686 | 1.00 | 9.59 | D | O |
| ATOM | 3878 | N | ASN | D | 597 | 13.198 | 60.803 | 59.031 | 1.00 | 12.50 | D | N |
| ATOM | 3879 | CA | ASN | D | 597 | 12.146 | 59.806 | 59.186 | 1.00 | 14.68 | D | C |
| ATOM | 3880 | CB | ASN | D | 597 | 12.592 | 58.470 | 58.548 | 1.00 | 14.36 | D | C |
| ATOM | 3881 | CG | ASN | D | 597 | 12.392 | 58.455 | 57.027 | 1.00 | 17.33 | D | C |
| ATOM | 3882 | OD1 | ASN | D | 597 | 11.703 | 59.308 | 56.485 | 1.00 | 16.82 | D | O |
| ATOM | 3883 | ND2 | ASN | D | 597 | 12.997 | 57.484 | 56.341 | 1.00 | 17.91 | D | N |
| ATOM | 3884 | C | ASN | D | 597 | 11.645 | 59.606 | 60.631 | 1.00 | 14.90 | D | C |
| ATOM | 3885 | O | ASN | D | 597 | 10.715 | 58.818 | 60.866 | 1.00 | 12.23 | D | O |
| ATOM | 3886 | N | LEU | D | 598 | 12.248 | 60.297 | 61.601 | 1.00 | 12.57 | D | N |
| ATOM | 3887 | CA | LEU | D | 598 | 11.757 | 60.178 | 62.986 | 1.00 | 15.10 | D | C |
| ATOM | 3888 | CB | LEU | D | 598 | 12.638 | 60.983 | 63.956 | 1.00 | 11.19 | D | C |
| ATOM | 3889 | CG | LEU | D | 598 | 13.979 | 60.305 | 64.275 | 1.00 | 12.28 | D | C |
| ATOM | 3890 | CD1 | LEU | D | 598 | 14.865 | 61.251 | 65.080 | 1.00 | 12.92 | D | C |
| ATOM | 3891 | CD2 | LEU | D | 598 | 13.734 | 58.998 | 65.039 | 1.00 | 10.16 | D | C |
| ATOM | 3892 | C | LEU | D | 598 | 10.314 | 60.712 | 63.023 | 1.00 | 14.68 | D | C |
| ATOM | 3893 | O | LEU | D | 598 | 9.508 | 60.339 | 63.871 | 1.00 | 15.65 | D | O |
| ATOM | 3894 | N | LYS | D | 599 | 10.007 | 61.592 | 62.080 | 1.00 | 16.20 | D | N |
| ATOM | 3895 | CA | LYS | D | 599 | 8.685 | 62.200 | 61.944 | 1.00 | 19.14 | D | C |
| ATOM | 3896 | CB | LYS | D | 599 | 8.662 | 63.143 | 60.740 | 1.00 | 21.41 | D | C |
| ATOM | 3897 | CG | LYS | D | 599 | 8.968 | 64.571 | 61.078 | 1.00 | 32.54 | D | C |
| ATOM | 3898 | CD | LYS | D | 599 | 7.677 | 65.391 | 61.235 | 1.00 | 40.44 | D | C |
| ATOM | 3899 | CE | LYS | D | 599 | 7.671 | 66.210 | 62.528 | 1.00 | 36.63 | D | C |
| ATOM | 3900 | NZ | LYS | D | 599 | 6.812 | 65.558 | 63.549 | 1.00 | 41.61 | D | N |
| ATOM | 3901 | C | LYS | D | 599 | 7.621 | 61.146 | 61.725 | 1.00 | 18.26 | D | C |
| ATOM | 3902 | O | LYS | D | 599 | 6.457 | 61.372 | 62.021 | 1.00 | 19.21 | D | O |
| ATOM | 3903 | N | LYS | D | 600 | 8.025 | 59.998 | 61.193 | 1.00 | 18.64 | D | N |
| ATOM | 3904 | CA | LYS | D | 600 | 7.084 | 58.924 | 60.907 | 1.00 | 18.93 | D | C |
| ATOM | 3905 | CB | LYS | D | 600 | 7.486 | 58.194 | 59.624 | 1.00 | 21.80 | D | C |
| ATOM | 3906 | CG | LYS | D | 600 | 7.500 | 59.048 | 58.357 | 1.00 | 23.99 | D | C |
| ATOM | 3907 | CD | LYS | D | 600 | 8.113 | 58.229 | 57.224 | 1.00 | 28.50 | D | C |
| ATOM | 3908 | CE | LYS | D | 600 | 8.347 | 59.049 | 55.968 | 1.00 | 33.37 | D | C |
| ATOM | 3909 | NZ | LYS | D | 600 | 8.901 | 58.186 | 54.875 | 1.00 | 36.64 | D | N |
| ATOM | 3910 | C | LYS | D | 600 | 6.949 | 57.890 | 62.018 | 1.00 | 20.66 | D | C |
| ATOM | 3911 | O | LYS | D | 600 | 6.128 | 56.979 | 61.909 | 1.00 | 21.09 | D | O |
| ATOM | 3912 | N | SER | D | 601 | 7.750 | 58.010 | 63.073 | 1.00 | 16.87 | D | N |
| ATOM | 3913 | CA | SER | D | 601 | 7.691 | 57.043 | 64.165 | 1.00 | 16.15 | D | C |
| ATOM | 3914 | CB | SER | D | 601 | 8.925 | 56.152 | 64.142 | 1.00 | 15.40 | D | C |
| ATOM | 3915 | OG | SER | D | 601 | 8.824 | 55.154 | 65.140 | 1.00 | 22.49 | D | O |
| ATOM | 3916 | C | SER | D | 601 | 7.601 | 57.719 | 65.525 | 1.00 | 15.86 | D | C |
| ATOM | 3917 | O | SER | D | 601 | 8.602 | 58.228 | 66.037 | 1.00 | 13.80 | D | O |
| ATOM | 3918 | N | PRO | D | 602 | 6.400 | 57.718 | 66.138 | 1.00 | 17.54 | D | N |
| ATOM | 3919 | CD | PRO | D | 602 | 5.150 | 57.090 | 65.663 | 1.00 | 16.57 | D | C |
| ATOM | 3920 | CA | PRO | D | 602 | 6.230 | 58.354 | 67.455 | 1.00 | 15.07 | D | C |
| ATOM | 3921 | CB | PRO | D | 602 | 4.748 | 58.142 | 67.778 | 1.00 | 11.33 | D | C |
| ATOM | 3922 | CG | PRO | D | 602 | 4.331 | 56.972 | 66.923 | 1.00 | 15.02 | D | C |
| ATOM | 3923 | C | PRO | D | 602 | 7.141 | 57.701 | 68.491 | 1.00 | 13.91 | D | C |
| ATOM | 3924 | O | PRO | D | 602 | 7.784 | 58.384 | 69.284 | 1.00 | 13.85 | D | O |
| ATOM | 3925 | N | VAL | D | 603 | 7.210 | 56.374 | 68.452 | 1.00 | 14.59 | D | N |
| ATOM | 3926 | CA | VAL | D | 603 | 8.026 | 55.637 | 69.407 | 1.00 | 14.90 | D | C |
| ATOM | 3927 | CB | VAL | D | 603 | 7.772 | 54.100 | 69.297 | 1.00 | 13.16 | D | C |
| ATOM | 3928 | CG1 | VAL | D | 603 | 8.552 | 53.362 | 70.378 | 1.00 | 13.67 | D | C |
| ATOM | 3929 | CG2 | VAL | D | 603 | 6.278 | 53.803 | 69.465 | 1.00 | 8.23 | D | C |
| ATOM | 3930 | C | VAL | D | 603 | 9.519 | 55.949 | 69.270 | 1.00 | 14.95 | D | C |
| ATOM | 3931 | O | VAL | D | 603 | 10.171 | 56.290 | 70.263 | 1.00 | 15.31 | D | O |
| ATOM | 3932 | N | LEU | D | 604 | 10.059 | 55.868 | 68.050 | 1.00 | 12.61 | D | N |
| ATOM | 3933 | CA | LEU | D | 604 | 11.473 | 56.151 | 67.855 | 1.00 | 11.50 | D | C |
| ATOM | 3934 | CB | LEU | D | 604 | 11.915 | 55.761 | 66.440 | 1.00 | 12.15 | D | C |
| ATOM | 3935 | CG | LEU | D | 604 | 12.285 | 54.296 | 66.195 | 1.00 | 11.18 | D | C |
| ATOM | 3936 | CD1 | LEU | D | 604 | 12.387 | 54.025 | 64.691 | 1.00 | 7.72 | D | C |
| ATOM | 3937 | CD2 | LEU | D | 604 | 13.606 | 54.011 | 66.871 | 1.00 | 10.09 | D | C |
| ATOM | 3938 | C | LEU | D | 604 | 11.781 | 57.624 | 68.115 | 1.00 | 11.22 | D | C |
| ATOM | 3939 | O | LEU | D | 604 | 12.817 | 57.957 | 68.698 | 1.00 | 9.59 | D | O |
| ATOM | 3940 | N | GLN | D | 605 | 10.889 | 58.505 | 67.669 | 1.00 | 11.22 | D | N |
| ATOM | 3941 | CA | GLN | D | 605 | 11.078 | 59.937 | 67.869 | 1.00 | 11.03 | D | C |
| ATOM | 3942 | CB | GLN | D | 605 | 9.956 | 60.733 | 67.204 | 1.00 | 7.30 | D | C |
| ATOM | 3943 | CG | GLN | D | 605 | 10.124 | 62.243 | 67.365 | 1.00 | 8.78 | D | C |
| ATOM | 3944 | CD | GLN | D | 605 | 8.990 | 63.003 | 66.749 | 1.00 | 11.42 | D | C |
| ATOM | 3945 | OE1 | GLN | D | 605 | 8.340 | 62.503 | 65.829 | 1.00 | 16.42 | D | O |
| ATOM | 3946 | NE2 | GLN | D | 605 | 8.735 | 64.206 | 67.237 | 1.00 | 7.64 | D | N |
| ATOM | 3947 | C | GLN | D | 605 | 11.106 | 60.260 | 69.365 | 1.00 | 10.12 | D | C |
| ATOM | 3948 | O | GLN | D | 605 | 11.913 | 61.062 | 69.813 | 1.00 | 11.94 | D | O |
| ATOM | 3949 | N | TYR | D | 606 | 10.219 | 59.635 | 70.129 | 1.00 | 9.52 | D | N |
| ATOM | 3950 | CA | TYR | D | 606 | 10.167 | 59.861 | 71.576 | 1.00 | 11.00 | D | C |
| ATOM | 3951 | CB | TYR | D | 606 | 8.890 | 59.240 | 72.158 | 1.00 | 9.94 | D | C |
| ATOM | 3952 | CG | TYR | D | 606 | 8.606 | 59.677 | 73.574 | 1.00 | 11.68 | D | C |
| ATOM | 3953 | CD1 | TYR | D | 606 | 8.494 | 61.028 | 73.899 | 1.00 | 12.58 | D | C |
| ATOM | 3954 | CE1 | TYR | D | 606 | 8.221 | 61.439 | 75.214 | 1.00 | 11.34 | D | C |
| ATOM | 3955 | CD2 | TYR | D | 606 | 8.444 | 58.736 | 74.596 | 1.00 | 11.77 | D | C |
| ATOM | 3956 | CE2 | TYR | D | 606 | 8.170 | 59.133 | 75.918 | 1.00 | 11.25 | D | C |
| ATOM | 3957 | CZ | TYR | D | 606 | 8.058 | 60.480 | 76.213 | 1.00 | 13.06 | D | C |
| ATOM | 3958 | OH | TYR | D | 606 | 7.762 | 60.865 | 77.501 | 1.00 | 14.91 | D | O |
| ATOM | 3959 | C | TYR | D | 606 | 11.409 | 59.269 | 72.250 | 1.00 | 9.25 | D | C |
| ATOM | 3960 | O | TYR | D | 606 | 11.963 | 59.863 | 73.178 | 1.00 | 10.21 | D | O |
| ATOM | 3961 | N | LEU | D | 607 | 11.848 | 58.103 | 71.774 | 1.00 | 9.51 | D | N |
| ATOM | 3962 | CA | LEU | D | 607 | 13.044 | 57.452 | 72.310 | 1.00 | 7.23 | D | C |
| ATOM | 3963 | CB | LEU | D | 607 | 13.222 | 56.068 | 71.677 | 1.00 | 7.71 | D | C |
| ATOM | 3964 | CG | LEU | D | 607 | 12.336 | 54.963 | 72.267 | 1.00 | 10.78 | D | C |
| ATOM | 3965 | CD1 | LEU | D | 607 | 12.502 | 53.690 | 71.469 | 1.00 | 10.89 | D | C |
| ATOM | 3966 | CD2 | LEU | D | 607 | 12.702 | 54.714 | 73.741 | 1.00 | 8.93 | D | C |
| ATOM | 3967 | C | LEU | D | 607 | 14.289 | 58.305 | 72.053 | 1.00 | 9.66 | D | C |
| ATOM | 3968 | O | LEU | D | 607 | 15.201 | 58.349 | 72.884 | 1.00 | 11.20 | D | O |
| ATOM | 3969 | N | PHE | D | 608 | 14.337 | 58.996 | 70.914 | 1.00 | 8.95 | D | N |
| ATOM | 3970 | CA | PHE | D | 608 | 15.496 | 59.832 | 70.606 | 1.00 | 6.31 | D | C |
| ATOM | 3971 | CB | PHE | D | 608 | 15.479 | 60.269 | 69.131 | 1.00 | 6.06 | D | C |
| ATOM | 3972 | CG | PHE | D | 608 | 16.224 | 59.327 | 68.210 | 1.00 | 7.81 | D | C |
| ATOM | 3973 | CD1 | PHE | D | 608 | 15.826 | 57.996 | 68.076 | 1.00 | 6.77 | D | C |
| ATOM | 3974 | CD2 | PHE | D | 608 | 17.344 | 59.761 | 67.508 | 1.00 | 5.53 | D | C |
| ATOM | 3975 | CE1 | PHE | D | 608 | 16.540 | 57.114 | 67.256 | 1.00 | 9.29 | D | C |
| ATOM | 3976 | CE2 | PHE | D | 608 | 18.072 | 58.883 | 66.682 | 1.00 | 4.26 | D | C |
| ATOM | 3977 | CZ | PHE | D | 608 | 17.672 | 57.565 | 66.555 | 1.00 | 8.07 | D | C |
| ATOM | 3978 | C | PHE | D | 608 | 15.475 | 61.053 | 71.529 | 1.00 | 8.65 | D | C |
| ATOM | 3979 | O | PHE | D | 608 | 16.527 | 61.620 | 71.855 | 1.00 | 6.67 | D | O |
| ATOM | 3980 | N | PHE | D | 609 | 14.274 | 61.472 | 71.940 | 1.00 | 9.26 | D | N |
| ATOM | 3981 | CA | PHE | D | 609 | 14.139 | 62.605 | 72.861 | 1.00 | 7.13 | D | C |
| ATOM | 3982 | CB | PHE | D | 609 | 12.689 | 63.081 | 72.928 | 1.00 | 8.72 | D | C |
| ATOM | 3983 | CG | PHE | D | 609 | 12.423 | 64.002 | 74.087 | 1.00 | 9.52 | D | C |
| ATOM | 3984 | CD1 | PHE | D | 609 | 11.880 | 63.511 | 75.277 | 1.00 | 9.19 | D | C |
| ATOM | 3985 | CD2 | PHE | D | 609 | 12.803 | 65.345 | 74.026 | 1.00 | 6.37 | D | C |
| ATOM | 3986 | CE1 | PHE | D | 609 | 11.729 | 64.351 | 76.398 | 1.00 | 6.52 | D | C |
| ATOM | 3987 | CE2 | PHE | D | 609 | 12.656 | 66.186 | 75.132 | 1.00 | 2.76 | D | C |
| ATOM | 3988 | CZ | PHE | D | 609 | 12.118 | 65.686 | 76.322 | 1.00 | 3.90 | D | C |
| ATOM | 3989 | C | PHE | D | 609 | 14.563 | 62.125 | 74.261 | 1.00 | 10.32 | D | C |
| ATOM | 3990 | O | PHE | D | 609 | 15.366 | 62.758 | 74.945 | 1.00 | 10.53 | D | O |
| ATOM | 3991 | N | LEU | D | 610 | 14.015 | 60.994 | 74.685 | 1.00 | 9.53 | D | N |
| ATOM | 3992 | CA | LEU | D | 610 | 14.355 | 60.455 | 75.995 | 1.00 | 11.19 | D | C |
| ATOM | 3993 | CB | LEU | D | 610 | 13.601 | 59.146 | 76.243 | 1.00 | 7.51 | D | C |
| ATOM | 3994 | CG | LEU | D | 610 | 12.095 | 59.282 | 76.454 | 1.00 | 9.07 | D | C |
| ATOM | 3995 | CD1 | LEU | D | 610 | 11.509 | 57.915 | 76.688 | 1.00 | 8.25 | D | C |
| ATOM | 3996 | CD2 | LEU | D | 610 | 11.788 | 60.213 | 77.640 | 1.00 | 8.85 | D | C |
| ATOM | 3997 | C | LEU | D | 610 | 15.862 | 60.221 | 76.190 | 1.00 | 12.71 | D | C |
| ATOM | 3998 | O | LEU | D | 610 | 16.411 | 60.537 | 77.255 | 1.00 | 14.54 | D | O |
| ATOM | 3999 | N | ALA | D | 611 | 16.528 | 59.665 | 75.179 | 1.00 | 10.66 | D | N |
| ATOM | 4000 | CA | ALA | D | 611 | 17.959 | 59.401 | 75.277 | 1.00 | 9.32 | D | C |
| ATOM | 4001 | CB | ALA | D | 611 | 18.323 | 58.148 | 74.468 | 1.00 | 8.90 | D | C |
| ATOM | 4002 | C | ALA | D | 611 | 18.791 | 60.600 | 74.805 | 1.00 | 9.54 | D | C |
| ATOM | 4003 | O | ALA | D | 611 | 20.017 | 60.555 | 74.797 | 1.00 | 10.01 | D | O |
| ATOM | 4004 | N | GLN | D | 612 | 18.114 | 61.680 | 74.439 | 1.00 | 11.52 | D | N |
| ATOM | 4005 | CA | GLN | D | 612 | 18.772 | 62.891 | 73.949 | 1.00 | 11.52 | D | C |
| ATOM | 4006 | CB | GLN | D | 612 | 19.349 | 63.687 | 75.119 | 1.00 | 12.30 | D | C |
| ATOM | 4007 | CG | GLN | D | 612 | 18.297 | 64.479 | 75.889 | 1.00 | 12.77 | D | C |
| ATOM | 4008 | CD | GLN | D | 612 | 17.651 | 65.559 | 75.041 | 1.00 | 15.60 | D | C |
| ATOM | 4009 | OE1 | GLN | D | 612 | 18.260 | 66.597 | 74.787 | 1.00 | 15.00 | D | O |
| ATOM | 4010 | NE2 | GLN | D | 612 | 16.411 | 65.321 | 74.600 | 1.00 | 9.06 | D | N |
| ATOM | 4011 | C | GLN | D | 612 | 19.864 | 62.609 | 72.909 | 1.00 | 13.08 | D | C |
| ATOM | 4012 | O | GLN | D | 612 | 20.960 | 63.167 | 72.979 | 1.00 | 13.47 | D | O |
| ATOM | 4013 | N | ILE | D | 613 | 19.555 | 61.741 | 71.943 | 1.00 | 12.62 | D | N |
| ATOM | 4014 | CA | ILE | D | 613 | 20.502 | 61.395 | 70.885 | 1.00 | 9.67 | D | C |
| ATOM | 4015 | CB | ILE | D | 613 | 19.969 | 60.206 | 70.065 | 1.00 | 9.34 | D | C |
| ATOM | 4016 | CG2 | ILE | D | 613 | 20.976 | 59.830 | 68.978 | 1.00 | 10.34 | D | C |
| ATOM | 4017 | CG1 | ILE | D | 613 | 19.660 | 59.032 | 70.997 | 1.00 | 7.38 | D | C |
| ATOM | 4018 | CD1 | ILE | D | 613 | 19.133 | 57.799 | 70.305 | 1.00 | 2.72 | D | C |
| ATOM | 4019 | C | ILE | D | 613 | 20.695 | 62.605 | 69.944 | 1.00 | 10.92 | D | C |
| ATOM | 4020 | O | ILE | D | 613 | 19.738 | 63.077 | 69.331 | 1.00 | 12.58 | D | O |
| ATOM | 4021 | N | PRO | D | 614 | 21.929 | 63.135 | 69.836 | 1.00 | 11.23 | D | N |
| ATOM | 4022 | CD | PRO | D | 614 | 23.177 | 62.723 | 70.519 | 1.00 | 11.56 | D | C |
| ATOM | 4023 | CA | PRO | D | 614 | 22.139 | 64.286 | 68.940 | 1.00 | 11.01 | D | C |
| ATOM | 4024 | CB | PRO | D | 614 | 23.599 | 64.689 | 69.177 | 1.00 | 10.09 | D | C |
| ATOM | 4025 | CG | PRO | D | 614 | 23.998 | 63.983 | 70.503 | 1.00 | 10.27 | D | C |
| ATOM | 4026 | C | PRO | D | 614 | 21.884 | 63.963 | 67.465 | 1.00 | 12.45 | D | C |
| ATOM | 4027 | O | PRO | D | 614 | 22.203 | 62.869 | 66.978 | 1.00 | 10.63 | D | O |
| ATOM | 4028 | N | ILE | D | 615 | 21.305 | 64.934 | 66.771 | 1.00 | 11.49 | D | N |
| ATOM | 4029 | CA | ILE | D | 615 | 20.983 | 64.812 | 65.358 | 1.00 | 10.71 | D | C |
| ATOM | 4030 | CB | ILE | D | 615 | 19.444 | 64.700 | 65.131 | 1.00 | 12.04 | D | C |
| ATOM | 4031 | CG2 | ILE | D | 615 | 19.147 | 64.509 | 63.646 | 1.00 | 10.42 | D | C |
| ATOM | 4032 | CG1 | ILE | D | 615 | 18.867 | 63.543 | 65.953 | 1.00 | 10.41 | D | C |
| ATOM | 4033 | CD1 | ILE | D | 615 | 17.407 | 63.740 | 66.332 | 1.00 | 9.46 | D | C |
| ATOM | 4034 | C | ILE | D | 615 | 21.476 | 66.040 | 64.610 | 1.00 | 10.01 | D | C |
| ATOM | 4035 | O | ILE | D | 615 | 21.044 | 67.158 | 64.900 | 1.00 | 10.67 | D | O |
| ATOM | 4036 | N | ALA | D | 616 | 22.401 | 65.837 | 63.672 | 1.00 | 8.83 | D | N |
| ATOM | 4037 | CA | ALA | D | 616 | 22.912 | 66.928 | 62.840 | 1.00 | 9.12 | D | C |
| ATOM | 4038 | CB | ALA | D | 616 | 24.324 | 66.598 | 62.348 | 1.00 | 7.87 | D | C |
| ATOM | 4039 | C | ALA | D | 616 | 21.938 | 66.998 | 61.658 | 1.00 | 9.18 | D | C |
| ATOM | 4040 | O | ALA | D | 616 | 21.798 | 66.022 | 60.928 | 1.00 | 8.67 | D | O |
| ATOM | 4041 | N | MET | D | 617 | 21.228 | 68.113 | 61.504 | 1.00 | 9.24 | D | N |
| ATOM | 4042 | CA | MET | D | 617 | 20.272 | 68.273 | 60.397 | 1.00 | 10.35 | D | C |
| ATOM | 4043 | CB | MET | D | 617 | 18.909 | 68.725 | 60.928 | 1.00 | 8.78 | D | C |
| ATOM | 4044 | CG | MET | D | 617 | 18.368 | 67.848 | 62.055 | 1.00 | 13.74 | D | C |
| ATOM | 4045 | SD | MET | D | 617 | 16.560 | 67.874 | 62.212 | 1.00 | 19.04 | D | S |
| ATOM | 4046 | CE | MET | D | 617 | 16.410 | 69.070 | 63.301 | 1.00 | 22.26 | D | C |
| ATOM | 4047 | C | MET | D | 617 | 20.801 | 69.289 | 59.360 | 1.00 | 12.53 | D | C |
| ATOM | 4048 | O | MET | D | 617 | 21.567 | 70.199 | 59.711 | 1.00 | 12.89 | D | O |
| ATOM | 4049 | N | SER | D | 618 | 20.388 | 69.123 | 58.096 | 1.00 | 13.26 | D | N |
| ATOM | 4050 | CA | SER | D | 618 | 20.827 | 69.975 | 56.972 | 1.00 | 13.35 | D | C |
| ATOM | 4051 | CB | SER | D | 618 | 21.788 | 69.195 | 56.073 | 1.00 | 14.71 | D | C |
| ATOM | 4052 | OG | SER | D | 618 | 22.875 | 68.651 | 56.790 | 1.00 | 15.85 | D | O |
| ATOM | 4053 | C | SER | D | 618 | 19.633 | 70.398 | 56.118 | 1.00 | 12.96 | D | C |
| ATOM | 4054 | O | SER | D | 618 | 19.427 | 69.856 | 55.039 | 1.00 | 11.65 | D | O |
| ATOM | 4055 | N | PRO | D | 619 | 18.833 | 71.365 | 56.591 | 1.00 | 12.42 | D | N |
| ATOM | 4056 | CD | PRO | D | 619 | 18.954 | 72.080 | 57.877 | 1.00 | 9.76 | D | C |
| ATOM | 4057 | CA | PRO | D | 619 | 17.663 | 71.803 | 55.817 | 1.00 | 12.20 | D | C |
| ATOM | 4058 | CB | PRO | D | 619 | 17.031 | 72.887 | 56.701 | 1.00 | 13.32 | D | C |
| ATOM | 4059 | CG | PRO | D | 619 | 17.547 | 72.550 | 58.115 | 1.00 | 14.17 | D | C |
| ATOM | 4060 | C | PRO | D | 619 | 17.880 | 72.268 | 54.363 | 1.00 | 13.40 | D | C |
| ATOM | 4061 | O | PRO | D | 619 | 17.032 | 72.003 | 53.512 | 1.00 | 13.56 | D | O |
| ATOM | 4062 | N | LEU | D | 620 | 18.981 | 72.961 | 54.074 | 1.00 | 11.78 | D | N |
| ATOM | 4063 | CA | LEU | D | 620 | 19.252 | 73.416 | 52.713 | 1.00 | 10.92 | D | C |
| ATOM | 4064 | CB | LEU | D | 620 | 20.443 | 74.382 | 52.694 | 1.00 | 9.09 | D | C |
| ATOM | 4065 | CG | LEU | D | 620 | 20.088 | 75.835 | 53.044 | 1.00 | 10.80 | D | C |
| ATOM | 4066 | CD1 | LEU | D | 620 | 21.334 | 76.720 | 52.974 | 1.00 | 9.90 | D | C |
| ATOM | 4067 | CD2 | LEU | D | 620 | 19.028 | 76.357 | 52.074 | 1.00 | 13.02 | D | C |
| ATOM | 4068 | C | LEU | D | 620 | 19.518 | 72.205 | 51.804 | 1.00 | 13.26 | D | C |
| ATOM | 4069 | O | LEU | D | 620 | 19.002 | 72.124 | 50.681 | 1.00 | 12.32 | D | O |
| ATOM | 4070 | N | SER | D | 621 | 20.321 | 71.261 | 52.282 | 1.00 | 13.41 | D | N |
| ATOM | 4071 | CA | SER | D | 621 | 20.581 | 70.055 | 51.509 | 1.00 | 14.58 | D | C |
| ATOM | 4072 | CB | SER | D | 621 | 21.646 | 69.204 | 52.195 | 1.00 | 16.91 | D | C |
| ATOM | 4073 | OG | SER | D | 621 | 21.541 | 67.849 | 51.799 | 1.00 | 12.85 | D | O |
| ATOM | 4074 | C | SER | D | 621 | 19.272 | 69.245 | 51.342 | 1.00 | 17.50 | D | C |
| ATOM | 4075 | O | SER | D | 621 | 18.948 | 68.796 | 50.234 | 1.00 | 17.80 | D | O |
| ATOM | 4076 | N | ASN | D | 622 | 18.509 | 69.075 | 52.423 | 1.00 | 14.25 | D | N |
| ATOM | 4077 | CA | ASN | D | 622 | 17.252 | 68.335 | 52.350 | 1.00 | 14.53 | D | C |
| ATOM | 4078 | CB | ASN | D | 622 | 16.538 | 68.317 | 53.709 | 1.00 | 14.68 | D | C |
| ATOM | 4079 | CG | ASN | D | 622 | 17.294 | 67.533 | 54.790 | 1.00 | 17.08 | D | C |
| ATOM | 4080 | OD1 | ASN | D | 622 | 17.052 | 67.740 | 55.978 | 1.00 | 16.35 | D | O |
| ATOM | 4081 | ND2 | ASN | D | 622 | 18.191 | 66.634 | 54.388 | 1.00 | 14.34 | D | N |
| ATOM | 4082 | C | ASN | D | 622 | 16.317 | 69.010 | 51.343 | 1.00 | 16.23 | D | C |
| ATOM | 4083 | O | ASN | D | 622 | 15.614 | 68.342 | 50.588 | 1.00 | 14.52 | D | O |
| ATOM | 4084 | N | ASN | D | 623 | 16.296 | 70.340 | 51.360 | 1.00 | 17.04 | D | N |
| ATOM | 4085 | CA | ASN | D | 623 | 15.439 | 71.111 | 50.470 | 1.00 | 21.02 | D | C |
| ATOM | 4086 | CB | ASN | D | 623 | 15.615 | 72.611 | 50.735 | 1.00 | 18.59 | D | C |
| ATOM | 4087 | CG | ASN | D | 623 | 14.889 | 73.493 | 49.715 | 1.00 | 17.34 | D | C |
| ATOM | 4088 | OD1 | ASN | D | 623 | 15.514 | 74.282 | 48.997 | 1.00 | 17.93 | D | O |
| ATOM | 4089 | ND2 | ASN | D | 623 | 13.575 | 73.375 | 49.660 | 1.00 | 12.23 | D | N |
| ATOM | 4090 | C | ASN | D | 623 | 15.774 | 70.787 | 49.026 | 1.00 | 26.93 | D | C |
| ATOM | 4091 | O | ASN | D | 623 | 14.890 | 70.724 | 48.183 | 1.00 | 29.64 | D | O |
| ATOM | 4092 | N | SER | D | 624 | 17.054 | 70.552 | 48.752 | 1.00 | 32.81 | D | N |
| ATOM | 4093 | CA | SER | D | 624 | 17.504 | 70.245 | 47.399 | 1.00 | 38.99 | D | C |
| ATOM | 4094 | CB | SER | D | 624 | 19.027 | 70.165 | 47.349 | 1.00 | 40.28 | D | C |
| ATOM | 4095 | OG | SER | D | 624 | 19.541 | 71.286 | 46.652 | 1.00 | 42.52 | D | O |
| ATOM | 4096 | C | SER | D | 624 | 16.904 | 68.992 | 46.763 | 1.00 | 41.40 | D | C |
| ATOM | 4097 | O | SER | D | 624 | 17.040 | 68.784 | 45.558 | 1.00 | 41.75 | D | O |
| ATOM | 4098 | N | LEU | D | 625 | 16.250 | 68.157 | 47.561 | 1.00 | 45.63 | D | N |
| ATOM | 4099 | CA | LEU | D | 625 | 15.604 | 66.970 | 47.017 | 1.00 | 48.12 | D | C |
| ATOM | 4100 | CB | LEU | D | 625 | 16.608 | 65.820 | 46.862 | 1.00 | 50.53 | D | C |
| ATOM | 4101 | CG | LEU | D | 625 | 16.552 | 65.046 | 45.523 | 1.00 | 55.66 | D | C |
| ATOM | 4102 | CD1 | LEU | D | 625 | 16.601 | 63.531 | 45.787 | 1.00 | 55.06 | D | C |
| ATOM | 4103 | CD2 | LEU | D | 625 | 15.281 | 65.412 | 44.730 | 1.00 | 55.77 | D | C |
| ATOM | 4104 | C | LEU | D | 625 | 14.425 | 66.505 | 47.867 | 1.00 | 48.35 | D | C |
| ATOM | 4105 | O | LEU | D | 625 | 13.292 | 66.983 | 47.727 | 1.00 | 48.44 | D | O |
| ATOM | 4106 | N | PHE | D | 626 | 14.720 | 65.566 | 48.754 | 1.00 | 47.67 | D | N |
| ATOM | 4107 | CA | PHE | D | 626 | 13.742 | 64.976 | 49.645 | 1.00 | 43.89 | D | C |
| ATOM | 4108 | CB | PHE | D | 626 | 14.483 | 64.315 | 50.812 | 1.00 | 41.98 | D | C |
| ATOM | 4109 | CG | PHE | D | 626 | 15.455 | 63.252 | 50.374 | 1.00 | 44.95 | D | C |
| ATOM | 4110 | CD1 | PHE | D | 626 | 14.991 | 62.054 | 49.801 | 1.00 | 44.08 | D | C |
| ATOM | 4111 | CD2 | PHE | D | 626 | 16.836 | 63.446 | 50.499 | 1.00 | 45.95 | D | C |
| ATOM | 4112 | CE1 | PHE | D | 626 | 15.890 | 61.055 | 49.350 | 1.00 | 43.84 | D | C |
| ATOM | 4113 | CE2 | PHE | D | 626 | 17.757 | 62.448 | 50.049 | 1.00 | 46.24 | D | C |
| ATOM | 4114 | CZ | PHE | D | 626 | 17.277 | 61.251 | 49.473 | 1.00 | 44.15 | D | C |
| ATOM | 4115 | C | PHE | D | 626 | 12.631 | 65.886 | 50.173 | 1.00 | 43.44 | D | C |
| ATOM | 4116 | O | PHE | D | 626 | 11.457 | 65.543 | 50.056 | 1.00 | 46.51 | D | O |
| ATOM | 4117 | N | LEU | D | 627 | 12.970 | 67.052 | 50.711 | 1.00 | 39.40 | D | N |
| ATOM | 4118 | CA | LEU | D | 627 | 11.934 | 67.895 | 51.307 | 1.00 | 37.86 | D | C |
| ATOM | 4119 | CB | LEU | D | 627 | 11.960 | 67.701 | 52.824 | 1.00 | 36.48 | D | C |
| ATOM | 4120 | CG | LEU | D | 627 | 10.704 | 67.220 | 53.541 | 1.00 | 33.27 | D | C |
| ATOM | 4121 | CD1 | LEU | D | 627 | 10.963 | 67.306 | 55.035 | 1.00 | 30.00 | D | C |
| ATOM | 4122 | CD2 | LEU | D | 627 | 9.495 | 68.038 | 53.108 | 1.00 | 30.23 | D | C |
| ATOM | 4123 | C | LEU | D | 627 | 11.993 | 69.384 | 51.029 | 1.00 | 37.44 | D | C |
| ATOM | 4124 | O | LEU | D | 627 | 13.070 | 69.975 | 51.015 | 1.00 | 41.17 | D | O |
| ATOM | 4125 | N | GLU | D | 628 | 10.826 | 69.995 | 50.849 | 1.00 | 35.50 | D | N |
| ATOM | 4126 | CA | GLU | D | 628 | 10.740 | 71.443 | 50.601 | 1.00 | 34.74 | D | C |
| ATOM | 4127 | CB | GLU | D | 628 | 9.333 | 71.785 | 50.131 | 1.00 | 35.21 | D | C |
| ATOM | 4128 | CG | GLU | D | 628 | 8.802 | 73.069 | 50.653 | 1.00 | 41.53 | D | C |
| ATOM | 4129 | CD | GLU | D | 628 | 7.366 | 73.258 | 50.256 | 1.00 | 46.94 | D | C |
| ATOM | 4130 | OE1 | GLU | D | 628 | 6.856 | 72.385 | 49.506 | 1.00 | 47.92 | D | O |
| ATOM | 4131 | OE2 | GLU | D | 628 | 6.760 | 74.270 | 50.690 | 1.00 | 48.14 | D | O |
| ATOM | 4132 | C | GLU | D | 628 | 11.089 | 72.176 | 51.911 | 1.00 | 31.53 | D | C |
| ATOM | 4133 | O | GLU | D | 628 | 10.546 | 71.842 | 52.971 | 1.00 | 28.76 | D | O |
| ATOM | 4134 | N | TYR | D | 629 | 11.973 | 73.174 | 51.828 | 1.00 | 24.76 | D | N |
| ATOM | 4135 | CA | TYR | D | 629 | 12.448 | 73.867 | 53.012 | 1.00 | 21.65 | D | C |
| ATOM | 4136 | CB | TYR | D | 629 | 13.100 | 75.196 | 52.667 | 1.00 | 20.38 | D | C |
| ATOM | 4137 | CG | TYR | D | 629 | 14.054 | 75.609 | 53.763 | 1.00 | 17.13 | D | C |
| ATOM | 4138 | CD1 | TYR | D | 629 | 13.587 | 76.256 | 54.915 | 1.00 | 21.05 | D | C |
| ATOM | 4139 | CE1 | TYR | D | 629 | 14.449 | 76.566 | 55.974 | 1.00 | 20.41 | D | C |
| ATOM | 4140 | CD2 | TYR | D | 629 | 15.402 | 75.289 | 53.692 | 1.00 | 15.20 | D | C |
| ATOM | 4141 | CE2 | TYR | D | 629 | 16.272 | 75.592 | 54.734 | 1.00 | 16.10 | D | C |
| ATOM | 4142 | CZ | TYR | D | 629 | 15.793 | 76.226 | 55.874 | 1.00 | 21.52 | D | C |
| ATOM | 4143 | OH | TYR | D | 629 | 16.656 | 76.490 | 56.918 | 1.00 | 21.33 | D | O |
| ATOM | 4144 | C | TYR | D | 629 | 11.486 | 74.086 | 54.156 | 1.00 | 21.99 | D | C |
| ATOM | 4145 | O | TYR | D | 629 | 11.717 | 73.582 | 55.248 | 1.00 | 22.46 | D | O |
| ATOM | 4146 | N | ALA | D | 630 | 10.418 | 74.834 | 53.920 | 1.00 | 22.20 | D | N |
| ATOM | 4147 | CA | ALA | D | 630 | 9.442 | 75.115 | 54.971 | 1.00 | 24.57 | D | C |
| ATOM | 4148 | CB | ALA | D | 630 | 8.352 | 76.022 | 54.429 | 1.00 | 23.67 | D | C |
| ATOM | 4149 | C | ALA | D | 630 | 8.806 | 73.881 | 55.625 | 1.00 | 25.12 | D | C |
| ATOM | 4150 | O | ALA | D | 630 | 8.246 | 73.982 | 56.718 | 1.00 | 27.56 | D | O |
| ATOM | 4151 | N | LYS | D | 631 | 8.897 | 72.727 | 54.971 | 1.00 | 21.97 | D | N |
| ATOM | 4152 | CA | LYS | D | 631 | 8.302 | 71.499 | 55.496 | 1.00 | 20.45 | D | C |
| ATOM | 4153 | CB | LYS | D | 631 | 7.762 | 70.657 | 54.338 | 1.00 | 24.07 | D | C |
| ATOM | 4154 | CG | LYS | D | 631 | 6.284 | 70.827 | 54.072 | 1.00 | 30.63 | D | C |
| ATOM | 4155 | CD | LYS | D | 631 | 6.005 | 72.017 | 53.170 | 1.00 | 38.32 | D | C |
| ATOM | 4156 | CE | LYS | D | 631 | 4.490 | 72.285 | 53.066 | 1.00 | 42.81 | D | C |
| ATOM | 4157 | NZ | LYS | D | 631 | 4.182 | 73.539 | 52.296 | 1.00 | 45.79 | D | N |
| ATOM | 4158 | C | LYS | D | 631 | 9.268 | 70.632 | 56.324 | 1.00 | 20.85 | D | C |
| ATOM | 4159 | O | LYS | D | 631 | 8.899 | 69.556 | 56.803 | 1.00 | 18.52 | D | O |
| ATOM | 4160 | N | ASN | D | 632 | 10.503 | 71.095 | 56.487 | 1.00 | 17.35 | D | N |
| ATOM | 4161 | CA | ASN | D | 632 | 11.504 | 70.345 | 57.242 | 1.00 | 15.86 | D | C |
| ATOM | 4162 | CB | ASN | D | 632 | 12.868 | 71.044 | 57.116 | 1.00 | 13.17 | D | C |
| ATOM | 4163 | CG | ASN | D | 632 | 14.030 | 70.115 | 57.412 | 1.00 | 17.50 | D | C |
| ATOM | 4164 | OD1 | ASN | D | 632 | 14.730 | 69.651 | 56.500 | 1.00 | 16.65 | D | O |
| ATOM | 4165 | ND2 | ASN | D | 632 | 14.242 | 69.829 | 58.690 | 1.00 | 10.90 | D | N |
| ATOM | 4166 | C | ASN | D | 632 | 11.122 | 70.207 | 58.727 | 1.00 | 13.52 | D | C |
| ATOM | 4167 | O | ASN | D | 632 | 10.744 | 71.183 | 59.364 | 1.00 | 13.68 | D | O |
| ATOM | 4168 | N | PRO | D | 633 | 11.227 | 68.993 | 59.296 | 1.00 | 15.10 | D | N |
| ATOM | 4169 | CD | PRO | D | 633 | 11.656 | 67.746 | 58.638 | 1.00 | 16.13 | D | C |
| ATOM | 4170 | CA | PRO | D | 633 | 10.891 | 68.767 | 60.716 | 1.00 | 16.23 | D | C |
| ATOM | 4171 | CB | PRO | D | 633 | 10.928 | 67.255 | 60.855 | 1.00 | 16.02 | D | C |
| ATOM | 4172 | CG | PRO | D | 633 | 11.914 | 66.826 | 59.791 | 1.00 | 16.17 | D | C |
| ATOM | 4173 | C | PRO | D | 633 | 11.853 | 69.452 | 61.709 | 1.00 | 17.04 | D | C |
| ATOM | 4174 | O | PRO | D | 633 | 11.651 | 69.384 | 62.921 | 1.00 | 15.42 | D | O |
| ATOM | 4175 | N | PHE | D | 634 | 12.885 | 70.119 | 61.193 | 1.00 | 15.05 | D | N |
| ATOM | 4176 | CA | PHE | D | 634 | 13.852 | 70.813 | 62.032 | 1.00 | 14.92 | D | C |
| ATOM | 4177 | CB | PHE | D | 634 | 14.754 | 71.707 | 61.173 | 1.00 | 12.16 | D | C |
| ATOM | 4178 | CG | PHE | D | 634 | 15.618 | 72.638 | 61.973 | 1.00 | 13.43 | D | C |
| ATOM | 4179 | CD1 | PHE | D | 634 | 15.258 | 73.972 | 62.130 | 1.00 | 11.28 | D | C |
| ATOM | 4180 | CD2 | PHE | D | 634 | 16.779 | 72.173 | 62.605 | 1.00 | 14.01 | D | C |
| ATOM | 4181 | CE1 | PHE | D | 634 | 16.032 | 74.832 | 62.906 | 1.00 | 12.62 | D | C |
| ATOM | 4182 | CE2 | PHE | D | 634 | 17.564 | 73.030 | 63.388 | 1.00 | 12.56 | D | C |
| ATOM | 4183 | CZ | PHE | D | 634 | 17.187 | 74.360 | 63.539 | 1.00 | 11.68 | D | C |
| ATOM | 4184 | C | PHE | D | 634 | 13.248 | 71.652 | 63.181 | 1.00 | 16.78 | D | C |
| ATOM | 4185 | O | PHE | D | 634 | 13.634 | 71.487 | 64.352 | 1.00 | 14.97 | D | O |
| ATOM | 4186 | N | LEU | D | 635 | 12.313 | 72.547 | 62.861 | 1.00 | 14.85 | D | N |
| ATOM | 4187 | CA | LEU | D | 635 | 11.731 | 73.395 | 63.894 | 1.00 | 12.81 | D | C |
| ATOM | 4188 | CB | LEU | D | 635 | 10.849 | 74.469 | 63.270 | 1.00 | 13.55 | D | C |
| ATOM | 4189 | CG | LEU | D | 635 | 10.176 | 75.409 | 64.273 | 1.00 | 10.16 | D | C |
| ATOM | 4190 | CD1 | LEU | D | 635 | 11.254 | 76.187 | 65.012 | 1.00 | 7.14 | D | C |
| ATOM | 4191 | CD2 | LEU | D | 635 | 9.217 | 76.342 | 63.547 | 1.00 | 8.48 | D | C |
| ATOM | 4192 | C | LEU | D | 635 | 10.922 | 72.599 | 64.906 | 1.00 | 14.49 | D | C |
| ATOM | 4193 | O | LEU | D | 635 | 10.994 | 72.859 | 66.109 | 1.00 | 16.56 | D | O |
| ATOM | 4194 | N | ASP | D | 636 | 10.144 | 71.643 | 64.416 | 1.00 | 12.07 | D | N |
| ATOM | 4195 | CA | ASP | D | 636 | 9.332 | 70.790 | 65.272 | 1.00 | 13.20 | D | C |
| ATOM | 4196 | CB | ASP | D | 636 | 8.556 | 69.789 | 64.428 | 1.00 | 12.12 | D | C |
| ATOM | 4197 | CG | ASP | D | 636 | 7.516 | 69.043 | 65.233 | 1.00 | 15.61 | D | C |
| ATOM | 4198 | OD1 | ASP | D | 636 | 6.737 | 69.697 | 65.964 | 1.00 | 16.46 | D | O |
| ATOM | 4199 | OD2 | ASP | D | 636 | 7.472 | 67.800 | 65.135 | 1.00 | 16.01 | D | O |
| ATOM | 4200 | C | ASP | D | 636 | 10.190 | 70.018 | 66.281 | 1.00 | 12.77 | D | C |
| ATOM | 4201 | O | ASP | D | 636 | 9.862 | 69.967 | 67.464 | 1.00 | 14.98 | D | O |
| ATOM | 4202 | N | PHE | D | 637 | 11.265 | 69.397 | 65.800 | 1.00 | 9.57 | D | N |
| ATOM | 4203 | CA | PHE | D | 637 | 12.177 | 68.649 | 66.653 | 1.00 | 10.67 | D | C |
| ATOM | 4204 | CB | PHE | D | 637 | 13.268 | 67.965 | 65.814 | 1.00 | 8.30 | D | C |
| ATOM | 4205 | CG | PHE | D | 637 | 12.765 | 66.812 | 64.975 | 1.00 | 11.77 | D | C |
| ATOM | 4206 | CD1 | PHE | D | 637 | 11.455 | 66.358 | 65.087 | 1.00 | 9.98 | D | C |
| ATOM | 4207 | CD2 | PHE | D | 637 | 13.619 | 66.166 | 64.078 | 1.00 | 13.61 | D | C |
| ATOM | 4208 | CE1 | PHE | D | 637 | 10.997 | 65.269 | 64.320 | 1.00 | 13.93 | D | C |
| ATOM | 4209 | CE2 | PHE | D | 637 | 13.177 | 65.077 | 63.304 | 1.00 | 13.12 | D | C |
| ATOM | 4210 | CZ | PHE | D | 637 | 11.864 | 64.625 | 63.426 | 1.00 | 11.16 | D | C |
| ATOM | 4211 | C | PHE | D | 637 | 12.842 | 69.583 | 67.671 | 1.00 | 10.39 | D | C |
| ATOM | 4212 | O | PHE | D | 637 | 12.984 | 69.240 | 68.842 | 1.00 | 8.75 | D | O |
| ATOM | 4213 | N | LEU | D | 638 | 13.245 | 70.760 | 67.214 | 1.00 | 7.74 | D | N |
| ATOM | 4214 | CA | LEU | D | 638 | 13.887 | 71.730 | 68.083 | 1.00 | 11.16 | D | C |
| ATOM | 4215 | CB | LEU | D | 638 | 14.299 | 72.960 | 67.285 | 1.00 | 12.32 | D | C |
| ATOM | 4216 | CG | LEU | D | 638 | 15.064 | 74.004 | 68.097 | 1.00 | 17.28 | D | C |
| ATOM | 4217 | CD1 | LEU | D | 638 | 16.462 | 73.454 | 68.419 | 1.00 | 21.25 | D | C |
| ATOM | 4218 | CD2 | LEU | D | 638 | 15.160 | 75.302 | 67.320 | 1.00 | 14.68 | D | C |
| ATOM | 4219 | C | LEU | D | 638 | 12.980 | 72.169 | 69.225 | 1.00 | 11.10 | D | C |
| ATOM | 4220 | O | LEU | D | 638 | 13.398 | 72.191 | 70.389 | 1.00 | 14.21 | D | O |
| ATOM | 4221 | N | GLN | D | 639 | 11.743 | 72.518 | 68.886 | 1.00 | 8.68 | D | N |
| ATOM | 4222 | CA | GLN | D | 639 | 10.765 | 72.967 | 69.864 | 1.00 | 11.12 | D | C |
| ATOM | 4223 | CB | GLN | D | 639 | 9.487 | 73.392 | 69.170 | 1.00 | 9.83 | D | C |
| ATOM | 4224 | CG | GLN | D | 639 | 9.628 | 74.689 | 68.391 | 1.00 | 13.91 | D | C |
| ATOM | 4225 | CD | GLN | D | 639 | 8.340 | 75.081 | 67.717 | 1.00 | 14.72 | D | C |
| ATOM | 4226 | OE1 | GLN | D | 639 | 7.550 | 74.224 | 67.313 | 1.00 | 17.65 | D | O |
| ATOM | 4227 | NE2 | GLN | D | 639 | 8.112 | 76.377 | 67.601 | 1.00 | 17.93 | D | N |
| ATOM | 4228 | C | GLN | D | 639 | 10.434 | 71.891 | 70.874 | 1.00 | 13.06 | D | C |
| ATOM | 4229 | O | GLN | D | 639 | 10.317 | 72.172 | 72.057 | 1.00 | 13.58 | D | O |
| ATOM | 4230 | N | LYS | D | 640 | 10.268 | 70.663 | 70.391 | 1.00 | 12.96 | D | N |
| ATOM | 4231 | CA | LYS | D | 640 | 9.956 | 69.532 | 71.246 | 1.00 | 11.65 | D | C |
| ATOM | 4232 | CB | LYS | D | 640 | 9.649 | 68.305 | 70.391 | 1.00 | 11.39 | D | C |
| ATOM | 4233 | CG | LYS | D | 640 | 8.381 | 68.441 | 69.565 | 1.00 | 12.26 | D | C |
| ATOM | 4234 | CD | LYS | D | 640 | 8.142 | 67.182 | 68.767 | 1.00 | 8.36 | D | C |
| ATOM | 4235 | CE | LYS | D | 640 | 6.747 | 67.156 | 68.170 | 1.00 | 5.41 | D | C |
| ATOM | 4236 | NZ | LYS | D | 640 | 6.683 | 66.099 | 67.118 | 1.00 | 7.58 | D | N |
| ATOM | 4237 | C | LYS | D | 640 | 11.076 | 69.196 | 72.232 | 1.00 | 11.92 | D | C |
| ATOM | 4238 | O | LYS | D | 640 | 10.825 | 68.559 | 73.243 | 1.00 | 11.79 | D | O |
| ATOM | 4239 | N | GLY | D | 641 | 12.305 | 69.616 | 71.932 | 1.00 | 12.54 | D | N |
| ATOM | 4240 | CA | GLY | D | 641 | 13.418 | 69.335 | 72.823 | 1.00 | 10.27 | D | C |
| ATOM | 4241 | C | GLY | D | 641 | 14.410 | 68.270 | 72.364 | 1.00 | 12.97 | D | C |
| ATOM | 4242 | O | GLY | D | 641 | 15.282 | 67.887 | 73.150 | 1.00 | 13.30 | D | O |
| ATOM | 4243 | N | LEU | D | 642 | 14.297 | 67.758 | 71.132 | 1.00 | 10.81 | D | N |
| ATOM | 4244 | CA | LEU | D | 642 | 15.275 | 66.758 | 70.680 | 1.00 | 9.83 | D | C |
| ATOM | 4245 | CB | LEU | D | 642 | 14.904 | 66.127 | 69.331 | 1.00 | 8.32 | D | C |
| ATOM | 4246 | CG | LEU | D | 642 | 13.596 | 65.391 | 68.953 | 1.00 | 13.29 | D | C |
| ATOM | 4247 | CD1 | LEU | D | 642 | 13.924 | 63.960 | 68.619 | 1.00 | 7.83 | D | C |
| ATOM | 4248 | CD2 | LEU | D | 642 | 12.516 | 65.487 | 70.016 | 1.00 | 8.67 | D | C |
| ATOM | 4249 | C | LEU | D | 642 | 16.608 | 67.489 | 70.543 | 1.00 | 9.17 | D | C |
| ATOM | 4250 | O | LEU | D | 642 | 16.644 | 68.706 | 70.307 | 1.00 | 8.53 | D | O |
| ATOM | 4251 | N | MET | D | 643 | 17.698 | 66.747 | 70.711 | 1.00 | 11.19 | D | N |
| ATOM | 4252 | CA | MET | D | 643 | 19.049 | 67.294 | 70.644 | 1.00 | 13.58 | D | C |
| ATOM | 4253 | CB | MET | D | 643 | 20.019 | 66.288 | 71.303 | 1.00 | 19.12 | D | C |
| ATOM | 4254 | CG | MET | D | 643 | 21.074 | 66.906 | 72.227 | 1.00 | 20.50 | D | C |
| ATOM | 4255 | SD | MET | D | 643 | 22.456 | 67.594 | 71.303 | 1.00 | 29.14 | D | S |
| ATOM | 4256 | CE | MET | D | 643 | 23.768 | 67.498 | 72.495 | 1.00 | 19.72 | D | C |
| ATOM | 4257 | C | MET | D | 643 | 19.457 | 67.584 | 69.180 | 1.00 | 13.69 | D | C |
| ATOM | 4258 | O | MET | D | 643 | 20.075 | 66.750 | 68.518 | 1.00 | 10.55 | D | O |
| ATOM | 4259 | N | ILE | D | 644 | 19.138 | 68.787 | 68.714 | 1.00 | 12.36 | D | N |
| ATOM | 4260 | CA | ILE | D | 644 | 19.392 | 69.196 | 67.334 | 1.00 | 13.52 | D | C |
| ATOM | 4261 | CB | ILE | D | 644 | 18.103 | 69.854 | 66.728 | 1.00 | 15.86 | D | C |
| ATOM | 4262 | CG2 | ILE | D | 644 | 18.331 | 70.208 | 65.289 | 1.00 | 15.36 | D | C |
| ATOM | 4263 | CG1 | ILE | D | 644 | 16.900 | 68.919 | 66.848 | 1.00 | 13.70 | D | C |
| ATOM | 4264 | CD1 | ILE | D | 644 | 17.099 | 67.595 | 66.219 | 1.00 | 13.69 | D | C |
| ATOM | 4265 | C | ILE | D | 644 | 20.545 | 70.179 | 67.059 | 1.00 | 12.88 | D | C |
| ATOM | 4266 | O | ILE | D | 644 | 20.774 | 71.123 | 67.816 | 1.00 | 12.09 | D | O |
| ATOM | 4267 | N | SER | D | 645 | 21.273 | 69.954 | 65.966 | 1.00 | 10.42 | D | N |
| ATOM | 4268 | CA | SER | D | 645 | 22.316 | 70.902 | 65.555 | 1.00 | 11.05 | D | C |
| ATOM | 4269 | CB | SER | D | 645 | 23.732 | 70.378 | 65.857 | 1.00 | 10.06 | D | C |
| ATOM | 4270 | OG | SER | D | 645 | 24.087 | 69.286 | 65.031 | 1.00 | 8.46 | D | O |
| ATOM | 4271 | C | SER | D | 645 | 22.140 | 71.146 | 64.046 | 1.00 | 13.03 | D | C |
| ATOM | 4272 | O | SER | D | 645 | 21.549 | 70.317 | 63.343 | 1.00 | 12.83 | D | O |
| ATOM | 4273 | N | LEU | D | 646 | 22.628 | 72.283 | 63.551 | 1.00 | 14.60 | D | N |
| ATOM | 4274 | CA | LEU | D | 646 | 22.520 | 72.591 | 62.127 | 1.00 | 14.09 | D | C |
| ATOM | 4275 | CB | LEU | D | 646 | 22.214 | 74.073 | 61.900 | 1.00 | 12.20 | D | C |
| ATOM | 4276 | CG | LEU | D | 646 | 20.739 | 74.456 | 61.994 | 1.00 | 9.81 | D | C |
| ATOM | 4277 | CD1 | LEU | D | 646 | 20.616 | 75.959 | 61.898 | 1.00 | 2.59 | D | C |
| ATOM | 4278 | CD2 | LEU | D | 646 | 19.938 | 73.759 | 60.906 | 1.00 | 4.29 | D | C |
| ATOM | 4279 | C | LEU | D | 646 | 23.837 | 72.236 | 61.462 | 1.00 | 15.70 | D | C |
| ATOM | 4280 | O | LEU | D | 646 | 24.925 | 72.444 | 62.031 | 1.00 | 14.56 | D | O |
| ATOM | 4281 | N | SER | D | 647 | 23.737 | 71.668 | 60.263 | 1.00 | 15.42 | D | N |
| ATOM | 4282 | CA | SER | D | 647 | 24.913 | 71.280 | 59.506 | 1.00 | 13.86 | D | C |
| ATOM | 4283 | CB | SER | D | 647 | 25.192 | 69.795 | 59.665 | 1.00 | 10.36 | D | C |
| ATOM | 4284 | OG | SER | D | 647 | 24.083 | 69.052 | 59.218 | 1.00 | 12.68 | D | O |
| ATOM | 4285 | C | SER | D | 647 | 24.733 | 71.623 | 58.032 | 1.00 | 16.57 | D | C |
| ATOM | 4286 | O | SER | D | 647 | 23.628 | 71.885 | 57.556 | 1.00 | 18.16 | D | O |
| ATOM | 4287 | N | THR | D | 648 | 25.842 | 71.564 | 57.315 | 1.00 | 13.68 | D | N |
| ATOM | 4288 | CA | THR | D | 648 | 25.923 | 71.938 | 55.927 | 1.00 | 11.50 | D | C |
| ATOM | 4289 | CB | THR | D | 648 | 27.241 | 72.692 | 55.824 | 1.00 | 15.16 | D | C |
| ATOM | 4290 | OG1 | THR | D | 648 | 27.000 | 74.022 | 55.368 | 1.00 | 23.64 | D | O |
| ATOM | 4291 | CG2 | THR | D | 648 | 28.237 | 71.952 | 55.013 | 1.00 | 11.60 | D | C |
| ATOM | 4292 | C | THR | D | 648 | 25.790 | 70.804 | 54.871 | 1.00 | 14.89 | D | C |
| ATOM | 4293 | O | THR | D | 648 | 25.121 | 70.976 | 53.837 | 1.00 | 11.40 | D | O |
| ATOM | 4294 | N | ASP | D | 649 | 26.402 | 69.647 | 55.139 | 1.00 | 13.30 | D | N |
| ATOM | 4295 | CA | ASP | D | 649 | 26.373 | 68.496 | 54.215 | 1.00 | 13.74 | D | C |
| ATOM | 4296 | CB | ASP | D | 649 | 24.959 | 68.272 | 53.667 | 1.00 | 13.06 | D | C |
| ATOM | 4297 | CG | ASP | D | 649 | 24.787 | 66.910 | 53.007 | 1.00 | 15.12 | D | C |
| ATOM | 4298 | OD1 | ASP | D | 649 | 25.760 | 66.130 | 52.951 | 1.00 | 20.09 | D | O |
| ATOM | 4299 | OD2 | ASP | D | 649 | 23.667 | 66.609 | 52.549 | 1.00 | 13.34 | D | O |
| ATOM | 4300 | C | ASP | D | 649 | 27.358 | 68.691 | 53.039 | 1.00 | 14.22 | D | C |
| ATOM | 4301 | O | ASP | D | 649 | 28.504 | 68.217 | 53.100 | 1.00 | 10.63 | D | O |
| ATOM | 4302 | N | ASP | D | 650 | 26.914 | 69.385 | 51.987 | 1.00 | 15.77 | D | N |
| ATOM | 4303 | CA | ASP | D | 650 | 27.754 | 69.662 | 50.801 | 1.00 | 16.34 | D | C |
| ATOM | 4304 | CB | ASP | D | 650 | 27.312 | 68.827 | 49.601 | 1.00 | 18.18 | D | C |
| ATOM | 4305 | CG | ASP | D | 650 | 27.611 | 67.347 | 49.765 | 1.00 | 25.07 | D | C |
| ATOM | 4306 | OD1 | ASP | D | 650 | 26.752 | 66.537 | 49.378 | 1.00 | 31.40 | D | O |
| ATOM | 4307 | OD2 | ASP | D | 650 | 28.699 | 66.977 | 50.266 | 1.00 | 27.19 | D | O |
| ATOM | 4308 | C | ASP | D | 650 | 27.676 | 71.130 | 50.385 | 1.00 | 16.27 | D | C |
| ATOM | 4309 | O | ASP | D | 650 | 26.891 | 71.486 | 49.518 | 1.00 | 17.78 | D | O |
| ATOM | 4310 | N | PRO | D | 651 | 28.486 | 72.000 | 51.005 | 1.00 | 16.27 | D | N |
| ATOM | 4311 | CD | PRO | D | 651 | 29.461 | 71.720 | 52.070 | 1.00 | 13.46 | D | C |
| ATOM | 4312 | CA | PRO | D | 651 | 28.463 | 73.421 | 50.654 | 1.00 | 16.02 | D | C |
| ATOM | 4313 | CB | PRO | D | 651 | 29.631 | 74.010 | 51.452 | 1.00 | 14.18 | D | C |
| ATOM | 4314 | CG | PRO | D | 651 | 29.813 | 73.092 | 52.573 | 1.00 | 14.08 | D | C |
| ATOM | 4315 | C | PRO | D | 651 | 28.622 | 73.684 | 49.149 | 1.00 | 16.88 | D | C |
| ATOM | 4316 | O | PRO | D | 651 | 27.964 | 74.558 | 48.605 | 1.00 | 14.11 | D | O |
| ATOM | 4317 | N | MET | D | 652 | 29.506 | 72.941 | 48.486 | 1.00 | 18.05 | D | N |
| ATOM | 4318 | CA | MET | D | 652 | 29.724 | 73.153 | 47.059 | 1.00 | 20.67 | D | C |
| ATOM | 4319 | CB | MET | D | 652 | 30.754 | 72.174 | 46.514 | 1.00 | 21.01 | D | C |
| ATOM | 4320 | CG | MET | D | 652 | 31.324 | 72.640 | 45.169 | 1.00 | 27.81 | D | C |
| ATOM | 4321 | SD | MET | D | 652 | 32.522 | 71.477 | 44.515 | 1.00 | 35.86 | D | S |
| ATOM | 4322 | CE | MET | D | 652 | 31.497 | 70.158 | 44.124 | 1.00 | 23.80 | D | C |
| ATOM | 4323 | C | MET | D | 652 | 28.434 | 73.047 | 46.244 | 1.00 | 19.07 | D | C |
| ATOM | 4324 | O | MET | D | 652 | 28.201 | 73.843 | 45.336 | 1.00 | 16.62 | D | O |
| ATOM | 4325 | N | GLN | D | 653 | 27.601 | 72.068 | 46.584 | 1.00 | 17.16 | D | N |
| ATOM | 4326 | CA | GLN | D | 653 | 26.315 | 71.863 | 45.915 | 1.00 | 18.10 | D | C |
| ATOM | 4327 | CB | GLN | D | 653 | 25.825 | 70.423 | 46.127 | 1.00 | 17.84 | D | C |
| ATOM | 4328 | CG | GLN | D | 653 | 26.292 | 69.428 | 45.110 | 1.00 | 25.58 | D | C |
| ATOM | 4329 | CD | GLN | D | 653 | 27.797 | 69.208 | 45.171 | 1.00 | 35.12 | D | C |
| ATOM | 4330 | OE1 | GLN | D | 653 | 28.535 | 69.557 | 44.233 | 1.00 | 36.56 | D | O |
| ATOM | 4331 | NE2 | GLN | D | 653 | 28.267 | 68.630 | 46.280 | 1.00 | 37.90 | D | N |
| ATOM | 4332 | C | GLN | D | 653 | 25.178 | 72.796 | 46.386 | 1.00 | 16.94 | D | C |
| ATOM | 4333 | O | GLN | D | 653 | 24.328 | 73.194 | 45.581 | 1.00 | 15.36 | D | O |
| ATOM | 4334 | N | PHE | D | 654 | 25.144 | 73.146 | 47.677 | 1.00 | 15.99 | D | N |
| ATOM | 4335 | CA | PHE | D | 654 | 24.022 | 73.959 | 48.188 | 1.00 | 15.71 | D | C |
| ATOM | 4336 | CB | PHE | D | 654 | 23.313 | 73.207 | 49.320 | 1.00 | 16.20 | D | C |
| ATOM | 4337 | CG | PHE | D | 654 | 23.185 | 71.727 | 49.089 | 1.00 | 18.10 | D | C |
| ATOM | 4338 | CD1 | PHE | D | 654 | 23.875 | 70.822 | 49.888 | 1.00 | 15.80 | D | C |
| ATOM | 4339 | CD2 | PHE | D | 654 | 22.369 | 71.239 | 48.076 | 1.00 | 16.10 | D | C |
| ATOM | 4340 | CE1 | PHE | D | 654 | 23.751 | 69.455 | 49.681 | 1.00 | 17.68 | D | C |
| ATOM | 4341 | CE2 | PHE | D | 654 | 22.239 | 69.872 | 47.856 | 1.00 | 15.55 | D | C |
| ATOM | 4342 | CZ | PHE | D | 654 | 22.929 | 68.977 | 48.660 | 1.00 | 17.18 | D | C |
| ATOM | 4343 | C | PHE | D | 654 | 24.205 | 75.386 | 48.670 | 1.00 | 14.86 | D | C |
| ATOM | 4344 | O | PHE | D | 654 | 23.219 | 76.110 | 48.811 | 1.00 | 17.34 | D | O |
| ATOM | 4345 | N | HIS | D | 655 | 25.431 | 75.809 | 48.928 | 1.00 | 16.22 | D | N |
| ATOM | 4346 | CA | HIS | D | 655 | 25.624 | 77.153 | 49.465 | 1.00 | 18.02 | D | C |
| ATOM | 4347 | CB | HIS | D | 655 | 26.406 | 77.031 | 50.782 | 1.00 | 14.95 | D | C |
| ATOM | 4348 | CG | HIS | D | 655 | 25.766 | 76.084 | 51.749 | 1.00 | 12.88 | D | C |
| ATOM | 4349 | CD2 | HIS | D | 655 | 25.739 | 74.731 | 51.784 | 1.00 | 11.77 | D | C |
| ATOM | 4350 | ND1 | HIS | D | 655 | 24.933 | 76.507 | 52.765 | 1.00 | 18.41 | D | N |
| ATOM | 4351 | CE1 | HIS | D | 655 | 24.418 | 75.455 | 53.379 | 1.00 | 13.59 | D | C |
| ATOM | 4352 | NE2 | HIS | D | 655 | 24.891 | 74.366 | 52.802 | 1.00 | 14.16 | D | N |
| ATOM | 4353 | C | HIS | D | 655 | 26.249 | 78.159 | 48.512 | 1.00 | 18.84 | D | C |
| ATOM | 4354 | O | HIS | D | 655 | 26.862 | 77.785 | 47.512 | 1.00 | 21.56 | D | O |
| ATOM | 4355 | N | PHE | D | 656 | 26.081 | 79.438 | 48.822 | 1.00 | 18.98 | D | N |
| ATOM | 4356 | CA | PHE | D | 656 | 26.591 | 80.499 | 47.961 | 1.00 | 21.42 | D | C |
| ATOM | 4357 | CB | PHE | D | 656 | 25.470 | 81.475 | 47.625 | 1.00 | 20.12 | D | C |
| ATOM | 4358 | CG | PHE | D | 656 | 24.311 | 80.847 | 46.916 | 1.00 | 22.06 | D | C |
| ATOM | 4359 | CD1 | PHE | D | 656 | 23.037 | 80.880 | 47.466 | 1.00 | 22.37 | D | C |
| ATOM | 4360 | CD2 | PHE | D | 656 | 24.485 | 80.256 | 45.671 | 1.00 | 25.16 | D | C |
| ATOM | 4361 | CE1 | PHE | D | 656 | 21.950 | 80.336 | 46.779 | 1.00 | 23.61 | D | C |
| ATOM | 4362 | CE2 | PHE | D | 656 | 23.401 | 79.709 | 44.978 | 1.00 | 23.90 | D | C |
| ATOM | 4363 | CZ | PHE | D | 656 | 22.137 | 79.752 | 45.532 | 1.00 | 22.85 | D | C |
| ATOM | 4364 | C | PHE | D | 656 | 27.763 | 81.310 | 48.486 | 1.00 | 24.39 | D | C |
| ATOM | 4365 | O | PHE | D | 656 | 28.396 | 82.038 | 47.713 | 1.00 | 26.24 | D | O |
| ATOM | 4366 | N | THR | D | 657 | 28.072 | 81.187 | 49.774 | 1.00 | 21.84 | D | N |
| ATOM | 4367 | CA | THR | D | 657 | 29.143 | 81.979 | 50.343 | 1.00 | 20.53 | D | C |
| ATOM | 4368 | CB | THR | D | 657 | 28.570 | 82.895 | 51.428 | 1.00 | 22.47 | D | C |
| ATOM | 4369 | OG1 | THR | D | 657 | 28.460 | 82.159 | 52.650 | 1.00 | 22.15 | D | O |
| ATOM | 4370 | CG2 | THR | D | 657 | 27.171 | 83.390 | 51.026 | 1.00 | 15.39 | D | C |
| ATOM | 4371 | C | THR | D | 657 | 30.287 | 81.172 | 50.937 | 1.00 | 22.42 | D | C |
| ATOM | 4372 | O | THR | D | 657 | 30.214 | 79.941 | 51.013 | 1.00 | 22.38 | D | O |
| ATOM | 4373 | N | LYS | D | 658 | 31.340 | 81.877 | 51.363 | 1.00 | 23.82 | D | N |
| ATOM | 4374 | CA | LYS | D | 658 | 32.513 | 81.246 | 51.989 | 1.00 | 27.48 | D | C |
| ATOM | 4375 | CB | LYS | D | 658 | 33.731 | 82.193 | 51.982 | 1.00 | 31.45 | D | C |
| ATOM | 4376 | CG | LYS | D | 658 | 33.859 | 83.099 | 50.748 | 1.00 | 42.88 | D | C |
| ATOM | 4377 | CD | LYS | D | 658 | 34.905 | 82.564 | 49.726 | 1.00 | 47.46 | D | C |
| ATOM | 4378 | CE | LYS | D | 658 | 34.398 | 82.626 | 48.266 | 1.00 | 44.93 | D | C |
| ATOM | 4379 | NZ | LYS | D | 658 | 34.082 | 81.271 | 47.733 | 1.00 | 43.44 | D | N |
| ATOM | 4380 | C | LYS | D | 658 | 32.202 | 80.861 | 53.445 | 1.00 | 24.82 | D | C |
| ATOM | 4381 | O | LYS | D | 658 | 33.049 | 80.303 | 54.140 | 1.00 | 26.17 | D | O |
| ATOM | 4382 | N | GLU | D | 659 | 30.991 | 81.174 | 53.899 | 1.00 | 22.33 | D | N |
| ATOM | 4383 | CA | GLU | D | 659 | 30.564 | 80.866 | 55.261 | 1.00 | 21.24 | D | C |
| ATOM | 4384 | CB | GLU | D | 659 | 30.376 | 82.160 | 56.049 | 1.00 | 22.88 | D | C |
| ATOM | 4385 | CG | GLU | D | 659 | 31.675 | 82.918 | 56.268 | 1.00 | 30.85 | D | C |
| ATOM | 4386 | CD | GLU | D | 659 | 31.568 | 83.953 | 57.369 | 1.00 | 35.69 | D | C |
| ATOM | 4387 | OE1 | GLU | D | 659 | 31.834 | 83.609 | 58.546 | 1.00 | 40.39 | D | O |
| ATOM | 4388 | OE2 | GLU | D | 659 | 31.213 | 85.107 | 57.056 | 1.00 | 36.48 | D | O |
| ATOM | 4389 | C | GLU | D | 659 | 29.249 | 80.100 | 55.191 | 1.00 | 18.94 | D | C |
| ATOM | 4390 | O | GLU | D | 659 | 28.190 | 80.610 | 55.583 | 1.00 | 16.72 | D | O |
| ATOM | 4391 | N | PRO | D | 660 | 29.302 | 78.850 | 54.696 | 1.00 | 16.28 | D | N |
| ATOM | 4392 | CD | PRO | D | 660 | 30.515 | 78.156 | 54.236 | 1.00 | 13.71 | D | C |
| ATOM | 4393 | CA | PRO | D | 660 | 28.115 | 78.007 | 54.563 | 1.00 | 14.29 | D | C |
| ATOM | 4394 | CB | PRO | D | 660 | 28.647 | 76.733 | 53.904 | 1.00 | 12.39 | D | C |
| ATOM | 4395 | CG | PRO | D | 660 | 30.076 | 76.732 | 54.188 | 1.00 | 12.87 | D | C |
| ATOM | 4396 | C | PRO | D | 660 | 27.337 | 77.723 | 55.849 | 1.00 | 13.23 | D | C |
| ATOM | 4397 | O | PRO | D | 660 | 26.108 | 77.716 | 55.824 | 1.00 | 12.68 | D | O |
| ATOM | 4398 | N | LEU | D | 661 | 28.037 | 77.493 | 56.960 | 1.00 | 15.07 | D | N |
| ATOM | 4399 | CA | LEU | D | 661 | 27.370 | 77.222 | 58.236 | 1.00 | 12.55 | D | C |
| ATOM | 4400 | CB | LEU | D | 661 | 28.387 | 76.934 | 59.348 | 1.00 | 14.88 | D | C |
| ATOM | 4401 | CG | LEU | D | 661 | 28.172 | 75.767 | 60.342 | 1.00 | 16.75 | D | C |
| ATOM | 4402 | CD1 | LEU | D | 661 | 28.589 | 76.219 | 61.715 | 1.00 | 8.92 | D | C |
| ATOM | 4403 | CD2 | LEU | D | 661 | 26.728 | 75.245 | 60.336 | 1.00 | 7.61 | D | C |
| ATOM | 4404 | C | LEU | D | 661 | 26.541 | 78.430 | 58.623 | 1.00 | 11.00 | D | C |
| ATOM | 4405 | O | LEU | D | 661 | 25.365 | 78.293 | 58.945 | 1.00 | 9.08 | D | O |
| ATOM | 4406 | N | MET | D | 662 | 27.149 | 79.613 | 58.586 | 1.00 | 12.43 | D | N |
| ATOM | 4407 | CA | MET | D | 662 | 26.430 | 80.838 | 58.944 | 1.00 | 14.15 | D | C |
| ATOM | 4408 | CB | MET | D | 662 | 27.346 | 82.052 | 58.800 | 1.00 | 16.81 | D | C |
| ATOM | 4409 | CG | MET | D | 662 | 28.467 | 82.087 | 59.839 | 1.00 | 19.91 | D | C |
| ATOM | 4410 | SD | MET | D | 662 | 27.825 | 81.913 | 61.520 | 1.00 | 22.50 | D | S |
| ATOM | 4411 | CE | MET | D | 662 | 27.533 | 83.663 | 61.956 | 1.00 | 20.59 | D | C |
| ATOM | 4412 | C | MET | D | 662 | 25.218 | 80.975 | 58.032 | 1.00 | 15.85 | D | C |
| ATOM | 4413 | O | MET | D | 662 | 24.159 | 81.448 | 58.440 | 1.00 | 15.06 | D | O |
| ATOM | 4414 | N | GLU | D | 663 | 25.383 | 80.541 | 56.789 | 1.00 | 15.41 | D | N |
| ATOM | 4415 | CA | GLU | D | 663 | 24.301 | 80.563 | 55.804 | 1.00 | 15.35 | D | C |
| ATOM | 4416 | CB | GLU | D | 663 | 24.837 | 80.087 | 54.444 | 1.00 | 19.46 | D | C |
| ATOM | 4417 | CG | GLU | D | 663 | 24.384 | 80.889 | 53.242 | 1.00 | 19.54 | D | C |
| ATOM | 4418 | CD | GLU | D | 663 | 24.965 | 80.363 | 51.929 | 1.00 | 19.77 | D | C |
| ATOM | 4419 | OE1 | GLU | D | 663 | 26.206 | 80.234 | 51.835 | 1.00 | 17.36 | D | O |
| ATOM | 4420 | OE2 | GLU | D | 663 | 24.165 | 80.082 | 51.006 | 1.00 | 20.16 | D | O |
| ATOM | 4421 | C | GLU | D | 663 | 23.138 | 79.662 | 56.249 | 1.00 | 11.54 | D | C |
| ATOM | 4422 | O | GLU | D | 663 | 21.989 | 80.102 | 56.218 | 1.00 | 9.36 | D | O |
| ATOM | 4423 | N | GLU | D | 664 | 23.435 | 78.411 | 56.646 | 1.00 | 11.87 | D | N |
| ATOM | 4424 | CA | GLU | D | 664 | 22.395 | 77.469 | 57.125 | 1.00 | 13.35 | D | C |
| ATOM | 4425 | CB | GLU | D | 664 | 22.973 | 76.169 | 57.667 | 1.00 | 12.62 | D | C |
| ATOM | 4426 | CG | GLU | D | 664 | 23.365 | 75.164 | 56.654 | 1.00 | 25.30 | D | C |
| ATOM | 4427 | CD | GLU | D | 664 | 22.204 | 74.409 | 56.012 | 1.00 | 20.71 | D | C |
| ATOM | 4428 | OE1 | GLU | D | 664 | 21.048 | 74.407 | 56.511 | 1.00 | 19.52 | D | O |
| ATOM | 4429 | OE2 | GLU | D | 664 | 22.484 | 73.802 | 54.970 | 1.00 | 20.89 | D | O |
| ATOM | 4430 | C | GLU | D | 664 | 21.637 | 78.087 | 58.285 | 1.00 | 12.61 | D | C |
| ATOM | 4431 | O | GLU | D | 664 | 20.406 | 77.994 | 58.337 | 1.00 | 13.74 | D | O |
| ATOM | 4432 | N | TYR | D | 665 | 22.389 | 78.687 | 59.221 | 1.00 | 10.82 | D | N |
| ATOM | 4433 | CA | TYR | D | 665 | 21.816 | 79.331 | 60.405 | 1.00 | 10.29 | D | C |
| ATOM | 4434 | CB | TYR | D | 665 | 22.911 | 79.820 | 61.359 | 1.00 | 9.73 | D | C |
| ATOM | 4435 | CG | TYR | D | 665 | 23.382 | 78.779 | 62.356 | 1.00 | 13.81 | D | C |
| ATOM | 4436 | CD1 | TYR | D | 665 | 24.318 | 77.807 | 61.993 | 1.00 | 10.22 | D | C |
| ATOM | 4437 | CE1 | TYR | D | 665 | 24.768 | 76.844 | 62.931 | 1.00 | 14.77 | D | C |
| ATOM | 4438 | CD2 | TYR | D | 665 | 22.901 | 78.772 | 63.679 | 1.00 | 14.03 | D | C |
| ATOM | 4439 | CE2 | TYR | D | 665 | 23.346 | 77.816 | 64.616 | 1.00 | 11.26 | D | C |
| ATOM | 4440 | CZ | TYR | D | 665 | 24.274 | 76.859 | 64.235 | 1.00 | 14.15 | D | C |
| ATOM | 4441 | OH | TYR | D | 665 | 24.707 | 75.898 | 65.130 | 1.00 | 14.52 | D | O |
| ATOM | 4442 | C | TYR | D | 665 | 20.936 | 80.502 | 60.012 | 1.00 | 10.47 | D | C |
| ATOM | 4443 | O | TYR | D | 665 | 19.822 | 80.625 | 60.523 | 1.00 | 11.94 | D | O |
| ATOM | 4444 | N | ALA | D | 666 | 21.416 | 81.344 | 59.090 | 1.00 | 10.49 | D | N |
| ATOM | 4445 | CA | ALA | D | 666 | 20.640 | 82.510 | 58.652 | 1.00 | 10.73 | D | C |
| ATOM | 4446 | CB | ALA | D | 666 | 21.441 | 83.343 | 57.656 | 1.00 | 8.15 | D | C |
| ATOM | 4447 | C | ALA | D | 666 | 19.291 | 82.148 | 58.051 | 1.00 | 8.78 | D | C |
| ATOM | 4448 | O | ALA | D | 666 | 18.251 | 82.644 | 58.484 | 1.00 | 7.86 | D | O |
| ATOM | 4449 | N | ILE | D | 667 | 19.277 | 81.266 | 57.062 | 1.00 | 11.71 | D | N |
| ATOM | 4450 | CA | ILE | D | 667 | 17.984 | 80.945 | 56.476 | 1.00 | 11.71 | D | C |
| ATOM | 4451 | CB | ILE | D | 667 | 18.117 | 80.150 | 55.158 | 1.00 | 13.17 | D | C |
| ATOM | 4452 | CG2 | ILE | D | 667 | 18.764 | 78.805 | 55.407 | 1.00 | 15.64 | D | C |
| ATOM | 4453 | CG1 | ILE | D | 667 | 16.728 | 79.986 | 54.534 | 1.00 | 15.66 | D | C |
| ATOM | 4454 | CD1 | ILE | D | 667 | 16.681 | 79.028 | 53.374 | 1.00 | 24.19 | D | C |
| ATOM | 4455 | C | ILE | D | 667 | 17.081 | 80.208 | 57.455 | 1.00 | 13.21 | D | C |
| ATOM | 4456 | O | ILE | D | 667 | 15.860 | 80.403 | 57.448 | 1.00 | 12.31 | D | O |
| ATOM | 4457 | N | ALA | D | 668 | 17.661 | 79.362 | 58.302 | 1.00 | 11.44 | D | N |
| ATOM | 4458 | CA | ALA | D | 668 | 16.840 | 78.669 | 59.295 | 1.00 | 12.64 | D | C |
| ATOM | 4459 | CB | ALA | D | 668 | 17.689 | 77.686 | 60.107 | 1.00 | 8.67 | D | C |
| ATOM | 4460 | C | ALA | D | 668 | 16.189 | 79.711 | 60.224 | 1.00 | 13.37 | D | C |
| ATOM | 4461 | O | ALA | D | 668 | 14.996 | 79.625 | 60.539 | 1.00 | 12.41 | D | O |
| ATOM | 4462 | N | ALA | D | 669 | 16.973 | 80.698 | 60.646 | 1.00 | 12.00 | D | N |
| ATOM | 4463 | CA | ALA | D | 669 | 16.452 | 81.741 | 61.511 | 1.00 | 13.87 | D | C |
| ATOM | 4464 | CB | ALA | D | 669 | 17.572 | 82.690 | 61.920 | 1.00 | 9.99 | D | C |
| ATOM | 4465 | C | ALA | D | 669 | 15.354 | 82.522 | 60.790 | 1.00 | 17.10 | D | C |
| ATOM | 4466 | O | ALA | D | 669 | 14.303 | 82.820 | 61.375 | 1.00 | 16.21 | D | O |
| ATOM | 4467 | N | GLN | D | 670 | 15.600 | 82.848 | 59.516 | 1.00 | 16.73 | D | N |
| ATOM | 4468 | CA | GLN | D | 670 | 14.648 | 83.628 | 58.730 | 1.00 | 17.03 | D | C |
| ATOM | 4469 | CB | GLN | D | 670 | 15.251 | 84.020 | 57.371 | 1.00 | 18.16 | D | C |
| ATOM | 4470 | CG | GLN | D | 670 | 16.643 | 84.652 | 57.407 | 1.00 | 23.48 | D | C |
| ATOM | 4471 | CD | GLN | D | 670 | 16.602 | 86.162 | 57.482 | 1.00 | 28.75 | D | C |
| ATOM | 4472 | OE1 | GLN | D | 670 | 15.631 | 86.741 | 57.982 | 1.00 | 34.13 | D | O |
| ATOM | 4473 | NE2 | GLN | D | 670 | 17.658 | 86.817 | 56.986 | 1.00 | 28.02 | D | N |
| ATOM | 4474 | C | GLN | D | 670 | 13.312 | 82.923 | 58.493 | 1.00 | 17.80 | D | C |
| ATOM | 4475 | O | GLN | D | 670 | 12.242 | 83.462 | 58.813 | 1.00 | 16.48 | D | O |
| ATOM | 4476 | N | VAL | D | 671 | 13.344 | 81.719 | 57.932 | 1.00 | 16.42 | D | N |
| ATOM | 4477 | CA | VAL | D | 671 | 12.077 | 81.062 | 57.672 | 1.00 | 16.12 | D | C |
| ATOM | 4478 | CB | VAL | D | 671 | 12.147 | 80.153 | 56.396 | 1.00 | 15.81 | D | C |
| ATOM | 4479 | CG1 | VAL | D | 671 | 13.537 | 80.141 | 55.844 | 1.00 | 16.73 | D | C |
| ATOM | 4480 | CG2 | VAL | D | 671 | 11.615 | 78.769 | 56.673 | 1.00 | 11.67 | D | C |
| ATOM | 4481 | C | VAL | D | 671 | 11.443 | 80.320 | 58.851 | 1.00 | 16.88 | D | C |
| ATOM | 4482 | O | VAL | D | 671 | 10.218 | 80.226 | 58.919 | 1.00 | 14.62 | D | O |
| ATOM | 4483 | N | PHE | D | 672 | 12.244 | 79.815 | 59.785 | 1.00 | 16.83 | D | N |
| ATOM | 4484 | CA | PHE | D | 672 | 11.659 | 79.135 | 60.939 | 1.00 | 17.67 | D | C |
| ATOM | 4485 | CB | PHE | D | 672 | 12.561 | 78.008 | 61.418 | 1.00 | 16.04 | D | C |
| ATOM | 4486 | CG | PHE | D | 672 | 12.600 | 76.852 | 60.485 | 1.00 | 15.15 | D | C |
| ATOM | 4487 | CD1 | PHE | D | 672 | 11.425 | 76.254 | 60.060 | 1.00 | 17.48 | D | C |
| ATOM | 4488 | CD2 | PHE | D | 672 | 13.803 | 76.386 | 59.990 | 1.00 | 15.23 | D | C |
| ATOM | 4489 | CE1 | PHE | D | 672 | 11.450 | 75.201 | 59.142 | 1.00 | 17.90 | D | C |
| ATOM | 4490 | CE2 | PHE | D | 672 | 13.841 | 75.343 | 59.080 | 1.00 | 16.82 | D | C |
| ATOM | 4491 | CZ | PHE | D | 672 | 12.661 | 74.748 | 58.653 | 1.00 | 16.83 | D | C |
| ATOM | 4492 | C | PHE | D | 672 | 11.400 | 80.117 | 62.069 | 1.00 | 19.10 | D | C |
| ATOM | 4493 | O | PHE | D | 672 | 10.852 | 79.741 | 63.099 | 1.00 | 20.53 | D | O |
| ATOM | 4494 | N | LYS | D | 673 | 11.793 | 81.372 | 61.861 | 1.00 | 20.09 | D | N |
| ATOM | 4495 | CA | LYS | D | 673 | 11.588 | 82.435 | 62.843 | 1.00 | 19.90 | D | C |
| ATOM | 4496 | CB | LYS | D | 673 | 10.093 | 82.762 | 62.927 | 1.00 | 19.84 | D | C |
| ATOM | 4497 | CG | LYS | D | 673 | 9.634 | 83.692 | 61.816 | 1.00 | 26.81 | D | C |
| ATOM | 4498 | CD | LYS | D | 673 | 8.140 | 83.629 | 61.617 | 1.00 | 32.61 | D | C |
| ATOM | 4499 | CE | LYS | D | 673 | 7.753 | 82.469 | 60.711 | 1.00 | 38.96 | D | C |
| ATOM | 4500 | NZ | LYS | D | 673 | 6.346 | 82.574 | 60.196 | 1.00 | 38.54 | D | N |
| ATOM | 4501 | C | LYS | D | 673 | 12.155 | 82.114 | 64.233 | 1.00 | 19.77 | D | C |
| ATOM | 4502 | O | LYS | D | 673 | 11.456 | 82.203 | 65.248 | 1.00 | 20.26 | D | O |
| ATOM | 4503 | N | LEU | D | 674 | 13.437 | 81.763 | 64.255 | 1.00 | 17.32 | D | N |
| ATOM | 4504 | CA | LEU | D | 674 | 14.163 | 81.420 | 65.474 | 1.00 | 17.36 | D | C |
| ATOM | 4505 | CB | LEU | D | 674 | 15.424 | 80.642 | 65.094 | 1.00 | 14.86 | D | C |
| ATOM | 4506 | CG | LEU | D | 674 | 15.421 | 79.118 | 64.985 | 1.00 | 16.80 | D | C |
| ATOM | 4507 | CD1 | LEU | D | 674 | 14.054 | 78.564 | 64.786 | 1.00 | 11.53 | D | C |
| ATOM | 4508 | CD2 | LEU | D | 674 | 16.334 | 78.732 | 63.862 | 1.00 | 18.05 | D | C |
| ATOM | 4509 | C | LEU | D | 674 | 14.584 | 82.663 | 66.268 | 1.00 | 16.11 | D | C |
| ATOM | 4510 | O | LEU | D | 674 | 14.971 | 83.667 | 65.674 | 1.00 | 15.70 | D | O |
| ATOM | 4511 | N | SER | D | 675 | 14.521 | 82.603 | 67.598 | 1.00 | 14.25 | D | N |
| ATOM | 4512 | CA | SER | D | 675 | 14.973 | 83.745 | 68.415 | 1.00 | 13.27 | D | C |
| ATOM | 4513 | CB | SER | D | 675 | 14.361 | 83.686 | 69.815 | 1.00 | 13.76 | D | C |
| ATOM | 4514 | OG | SER | D | 675 | 14.876 | 82.578 | 70.542 | 1.00 | 16.54 | D | O |
| ATOM | 4515 | C | SER | D | 675 | 16.488 | 83.609 | 68.527 | 1.00 | 12.45 | D | C |
| ATOM | 4516 | O | SER | D | 675 | 17.055 | 82.571 | 68.157 | 1.00 | 11.83 | D | O |
| ATOM | 4517 | N | THR | D | 676 | 17.168 | 84.627 | 69.029 | 1.00 | 14.00 | D | N |
| ATOM | 4518 | CA | THR | D | 676 | 18.610 | 84.487 | 69.139 | 1.00 | 15.80 | D | C |
| ATOM | 4519 | CB | THR | D | 676 | 19.297 | 85.852 | 69.415 | 1.00 | 16.96 | D | C |
| ATOM | 4520 | OG1 | THR | D | 676 | 20.435 | 85.659 | 70.262 | 1.00 | 21.48 | D | O |
| ATOM | 4521 | CG2 | THR | D | 676 | 18.337 | 86.806 | 70.043 | 1.00 | 25.14 | D | C |
| ATOM | 4522 | C | THR | D | 676 | 18.939 | 83.432 | 70.207 | 1.00 | 14.99 | D | C |
| ATOM | 4523 | O | THR | D | 676 | 19.969 | 82.760 | 70.128 | 1.00 | 17.26 | D | O |
| ATOM | 4524 | N | CYS | D | 677 | 18.043 | 83.252 | 71.180 | 1.00 | 15.59 | D | N |
| ATOM | 4525 | CA | CYS | D | 677 | 18.246 | 82.233 | 72.214 | 1.00 | 12.57 | D | C |
| ATOM | 4526 | CB | CYS | D | 677 | 17.193 | 82.358 | 73.329 | 1.00 | 10.89 | D | C |
| ATOM | 4527 | SG | CYS | D | 677 | 17.482 | 81.217 | 74.739 | 1.00 | 16.04 | D | S |
| ATOM | 4528 | C | CYS | D | 677 | 18.147 | 80.848 | 71.554 | 1.00 | 12.98 | D | C |
| ATOM | 4529 | O | CYS | D | 677 | 18.923 | 79.944 | 71.867 | 1.00 | 12.13 | D | O |
| ATOM | 4530 | N | ASP | D | 678 | 17.194 | 80.688 | 70.633 | 1.00 | 12.42 | D | N |
| ATOM | 4531 | CA | ASP | D | 678 | 17.008 | 79.424 | 69.897 | 1.00 | 10.17 | D | C |
| ATOM | 4532 | CB | ASP | D | 678 | 15.881 | 79.545 | 68.859 | 1.00 | 12.55 | D | C |
| ATOM | 4533 | CG | ASP | D | 678 | 14.501 | 79.690 | 69.485 | 1.00 | 17.28 | D | C |
| ATOM | 4534 | OD1 | ASP | D | 678 | 14.301 | 79.184 | 70.616 | 1.00 | 19.17 | D | O |
| ATOM | 4535 | OD2 | ASP | D | 678 | 13.614 | 80.307 | 68.847 | 1.00 | 15.03 | D | O |
| ATOM | 4536 | C | ASP | D | 678 | 18.292 | 79.098 | 69.143 | 1.00 | 10.42 | D | C |
| ATOM | 4537 | O | ASP | D | 678 | 18.792 | 77.981 | 69.194 | 1.00 | 12.52 | D | O |
| ATOM | 4538 | N | MET | D | 679 | 18.821 | 80.088 | 68.438 | 1.00 | 13.03 | D | N |
| ATOM | 4539 | CA | MET | D | 679 | 20.050 | 79.922 | 67.666 | 1.00 | 14.07 | D | C |
| ATOM | 4540 | CB | MET | D | 679 | 20.342 | 81.205 | 66.889 | 1.00 | 17.53 | D | C |
| ATOM | 4541 | CG | MET | D | 679 | 19.234 | 81.622 | 65.905 | 1.00 | 25.73 | D | C |
| ATOM | 4542 | SD | MET | D | 679 | 19.800 | 83.008 | 64.863 | 1.00 | 35.85 | D | S |
| ATOM | 4543 | CE | MET | D | 679 | 18.945 | 84.369 | 65.557 | 1.00 | 31.18 | D | C |
| ATOM | 4544 | C | MET | D | 679 | 21.272 | 79.568 | 68.517 | 1.00 | 14.30 | D | C |
| ATOM | 4545 | O | MET | D | 679 | 22.070 | 78.707 | 68.149 | 1.00 | 12.99 | D | O |
| ATOM | 4546 | N | CYS | D | 680 | 21.435 | 80.250 | 69.647 | 1.00 | 15.13 | D | N |
| ATOM | 4547 | CA | CYS | D | 680 | 22.584 | 79.977 | 70.503 | 1.00 | 15.58 | D | C |
| ATOM | 4548 | CB | CYS | D | 680 | 22.727 | 81.081 | 71.563 | 1.00 | 15.69 | D | C |
| ATOM | 4549 | SG | CYS | D | 680 | 23.184 | 82.697 | 70.842 | 1.00 | 24.55 | D | S |
| ATOM | 4550 | C | CYS | D | 680 | 22.442 | 78.595 | 71.147 | 1.00 | 14.01 | D | C |
| ATOM | 4551 | O | CYS | D | 680 | 23.445 | 77.948 | 71.476 | 1.00 | 12.40 | D | O |
| ATOM | 4552 | N | GLU | D | 681 | 21.198 | 78.142 | 71.313 | 1.00 | 11.25 | D | N |
| ATOM | 4553 | CA | GLU | D | 681 | 20.963 | 76.829 | 71.889 | 1.00 | 11.41 | D | C |
| ATOM | 4554 | CB | GLU | D | 681 | 19.485 | 76.642 | 72.270 | 1.00 | 9.73 | D | C |
| ATOM | 4555 | CG | GLU | D | 681 | 19.238 | 75.304 | 72.963 | 1.00 | 13.16 | D | C |
| ATOM | 4556 | CD | GLU | D | 681 | 17.772 | 75.004 | 73.294 | 1.00 | 12.70 | D | C |
| ATOM | 4557 | OE1 | GLU | D | 681 | 16.843 | 75.673 | 72.786 | 1.00 | 12.67 | D | O |
| ATOM | 4558 | OE2 | GLU | D | 681 | 17.547 | 74.064 | 74.079 | 1.00 | 14.39 | D | O |
| ATOM | 4559 | C | GLU | D | 681 | 21.395 | 75.776 | 70.858 | 1.00 | 11.78 | D | C |
| ATOM | 4560 | O | GLU | D | 681 | 21.992 | 74.767 | 71.218 | 1.00 | 12.74 | D | O |
| ATOM | 4561 | N | VAL | D | 682 | 21.113 | 76.022 | 69.576 | 1.00 | 11.58 | D | N |
| ATOM | 4562 | CA | VAL | D | 682 | 21.506 | 75.077 | 68.513 | 1.00 | 9.18 | D | C |
| ATOM | 4563 | CB | VAL | D | 682 | 20.883 | 75.483 | 67.136 | 1.00 | 7.18 | D | C |
| ATOM | 4564 | CG1 | VAL | D | 682 | 21.543 | 74.709 | 65.995 | 1.00 | 6.76 | D | C |
| ATOM | 4565 | CG2 | VAL | D | 682 | 19.372 | 75.223 | 67.163 | 1.00 | 3.38 | D | C |
| ATOM | 4566 | C | VAL | D | 682 | 23.028 | 75.055 | 68.425 | 1.00 | 8.10 | D | C |
| ATOM | 4567 | O | VAL | D | 682 | 23.632 | 73.988 | 68.331 | 1.00 | 12.28 | D | O |
| ATOM | 4568 | N | ALA | D | 683 | 23.646 | 76.235 | 68.479 | 1.00 | 6.69 | D | N |
| ATOM | 4569 | CA | ALA | D | 683 | 25.101 | 76.334 | 68.441 | 1.00 | 6.77 | D | C |
| ATOM | 4570 | CB | ALA | D | 683 | 25.543 | 77.792 | 68.560 | 1.00 | 4.45 | D | C |
| ATOM | 4571 | C | ALA | D | 683 | 25.720 | 75.517 | 69.569 | 1.00 | 9.73 | D | C |
| ATOM | 4572 | O | ALA | D | 683 | 26.685 | 74.780 | 69.338 | 1.00 | 9.86 | D | O |
| ATOM | 4573 | N | ARG | D | 684 | 25.175 | 75.649 | 70.789 | 1.00 | 11.88 | D | N |
| ATOM | 4574 | CA | ARG | D | 684 | 25.703 | 74.915 | 71.945 | 1.00 | 11.62 | D | C |
| ATOM | 4575 | CB | ARG | D | 684 | 24.975 | 75.337 | 73.234 | 1.00 | 13.08 | D | C |
| ATOM | 4576 | CG | ARG | D | 684 | 25.459 | 74.610 | 74.496 | 1.00 | 13.12 | D | C |
| ATOM | 4577 | CD | ARG | D | 684 | 24.806 | 75.190 | 75.771 | 1.00 | 14.28 | D | C |
| ATOM | 4578 | NE | ARG | D | 684 | 25.347 | 74.589 | 76.999 | 1.00 | 15.82 | D | N |
| ATOM | 4579 | CZ | ARG | D | 684 | 24.875 | 73.485 | 77.577 | 1.00 | 12.38 | D | C |
| ATOM | 4580 | NH1 | ARG | D | 684 | 23.844 | 72.842 | 77.050 | 1.00 | 11.23 | D | N |
| ATOM | 4581 | NH2 | ARG | D | 684 | 25.446 | 73.012 | 78.677 | 1.00 | 16.17 | D | N |
| ATOM | 4582 | C | ARG | D | 684 | 25.563 | 73.407 | 71.715 | 1.00 | 10.57 | D | C |
| ATOM | 4583 | O | ARG | D | 684 | 26.487 | 72.634 | 71.985 | 1.00 | 12.71 | D | O |
| ATOM | 4584 | N | ASN | D | 685 | 24.407 | 72.981 | 71.223 | 1.00 | 8.28 | D | N |
| ATOM | 4585 | CA | ASN | D | 685 | 24.203 | 71.570 | 70.948 | 1.00 | 9.71 | D | C |
| ATOM | 4586 | CB | ASN | D | 685 | 22.818 | 71.334 | 70.337 | 1.00 | 13.39 | D | C |
| ATOM | 4587 | CG | ASN | D | 685 | 21.685 | 71.525 | 71.338 | 1.00 | 15.48 | D | C |
| ATOM | 4588 | OD1 | ASN | D | 685 | 21.915 | 71.651 | 72.537 | 1.00 | 14.96 | D | O |
| ATOM | 4589 | ND2 | ASN | D | 685 | 20.449 | 71.541 | 70.838 | 1.00 | 12.76 | D | N |
| ATOM | 4590 | C | ASN | D | 685 | 25.258 | 71.048 | 69.966 | 1.00 | 12.26 | D | C |
| ATOM | 4591 | O | ASN | D | 685 | 25.714 | 69.910 | 70.078 | 1.00 | 13.07 | D | O |
| ATOM | 4592 | N | SER | D | 686 | 25.638 | 71.873 | 68.992 | 1.00 | 11.26 | D | N |
| ATOM | 4593 | CA | SER | D | 686 | 26.620 | 71.452 | 67.997 | 1.00 | 11.96 | D | C |
| ATOM | 4594 | CB | SER | D | 686 | 26.704 | 72.484 | 66.843 | 1.00 | 10.20 | D | C |
| ATOM | 4595 | OG | SER | D | 686 | 27.446 | 73.650 | 67.174 | 1.00 | 7.13 | D | O |
| ATOM | 4596 | C | SER | D | 686 | 27.983 | 71.222 | 68.631 | 1.00 | 11.34 | D | C |
| ATOM | 4597 | O | SER | D | 686 | 28.683 | 70.276 | 68.265 | 1.00 | 13.22 | D | O |
| ATOM | 4598 | N | VAL | D | 687 | 28.367 | 72.074 | 69.584 | 1.00 | 11.94 | D | N |
| ATOM | 4599 | CA | VAL | D | 687 | 29.649 | 71.891 | 70.270 | 1.00 | 11.31 | D | C |
| ATOM | 4600 | CB | VAL | D | 687 | 30.038 | 73.104 | 71.145 | 1.00 | 13.08 | D | C |
| ATOM | 4601 | CG1 | VAL | D | 687 | 31.466 | 72.913 | 71.693 | 1.00 | 7.20 | D | C |
| ATOM | 4602 | CG2 | VAL | D | 687 | 29.967 | 74.386 | 70.303 | 1.00 | 10.04 | D | C |
| ATOM | 4603 | C | VAL | D | 687 | 29.603 | 70.656 | 71.150 | 1.00 | 10.56 | D | C |
| ATOM | 4604 | O | VAL | D | 687 | 30.573 | 69.917 | 71.228 | 1.00 | 14.06 | D | O |
| ATOM | 4605 | N | LEU | D | 688 | 28.467 | 70.422 | 71.794 | 1.00 | 10.34 | D | N |
| ATOM | 4606 | CA | LEU | D | 688 | 28.302 | 69.248 | 72.646 | 1.00 | 11.23 | D | C |
| ATOM | 4607 | CB | LEU | D | 688 | 26.945 | 69.308 | 73.367 | 1.00 | 7.11 | D | C |
| ATOM | 4608 | CG | LEU | D | 688 | 26.792 | 70.283 | 74.530 | 1.00 | 10.83 | D | C |
| ATOM | 4609 | CD1 | LEU | D | 688 | 25.362 | 70.205 | 75.067 | 1.00 | 7.03 | D | C |
| ATOM | 4610 | CD2 | LEU | D | 688 | 27.805 | 69.934 | 75.620 | 1.00 | 5.35 | D | C |
| ATOM | 4611 | C | LEU | D | 688 | 28.357 | 67.968 | 71.802 | 1.00 | 12.76 | D | C |
| ATOM | 4612 | O | LEU | D | 688 | 28.921 | 66.940 | 72.215 | 1.00 | 13.04 | D | O |
| ATOM | 4613 | N | GLN | D | 689 | 27.751 | 68.031 | 70.619 | 1.00 | 13.51 | D | N |
| ATOM | 4614 | CA | GLN | D | 689 | 27.697 | 66.882 | 69.721 | 1.00 | 11.94 | D | C |
| ATOM | 4615 | CB | GLN | D | 689 | 26.644 | 67.134 | 68.635 | 1.00 | 10.97 | D | C |
| ATOM | 4616 | CG | GLN | D | 689 | 26.596 | 66.051 | 67.586 | 1.00 | 10.36 | D | C |
| ATOM | 4617 | CD | GLN | D | 689 | 25.445 | 66.222 | 66.606 | 1.00 | 11.83 | D | C |
| ATOM | 4618 | OE1 | GLN | D | 689 | 25.124 | 65.306 | 65.852 | 1.00 | 15.35 | D | O |
| ATOM | 4619 | NE2 | GLN | D | 689 | 24.830 | 67.393 | 66.604 | 1.00 | 8.14 | D | N |
| ATOM | 4620 | C | GLN | D | 689 | 29.025 | 66.499 | 69.060 | 1.00 | 9.30 | D | C |
| ATOM | 4621 | O | GLN | D | 689 | 29.344 | 65.318 | 68.937 | 1.00 | 11.08 | D | O |
| ATOM | 4622 | N | CYS | D | 690 | 29.810 | 67.493 | 68.663 | 1.00 | 10.70 | D | N |
| ATOM | 4623 | CA | CYS | D | 690 | 31.061 | 67.248 | 67.946 | 1.00 | 10.85 | D | C |
| ATOM | 4624 | CB | CYS | D | 690 | 31.581 | 68.568 | 67.377 | 1.00 | 10.92 | D | C |
| ATOM | 4625 | SG | CYS | D | 690 | 32.347 | 69.625 | 68.589 | 1.00 | 15.51 | D | S |
| ATOM | 4626 | C | CYS | D | 690 | 32.201 | 66.510 | 68.641 | 1.00 | 14.05 | D | C |
| ATOM | 4627 | O | CYS | D | 690 | 32.152 | 66.237 | 69.834 | 1.00 | 16.04 | D | O |
| ATOM | 4628 | N | GLY | D | 691 | 33.238 | 66.198 | 67.870 | 1.00 | 14.34 | D | N |
| ATOM | 4629 | CA | GLY | D | 691 | 34.379 | 65.477 | 68.396 | 1.00 | 15.07 | D | C |
| ATOM | 4630 | C | GLY | D | 691 | 35.556 | 66.339 | 68.805 | 1.00 | 16.75 | D | C |
| ATOM | 4631 | O | GLY | D | 691 | 36.678 | 65.852 | 68.881 | 1.00 | 21.23 | D | O |
| ATOM | 4632 | N | ILE | D | 692 | 35.312 | 67.615 | 69.071 | 1.00 | 14.13 | D | N |
| ATOM | 4633 | CA | ILE | D | 692 | 36.372 | 68.511 | 69.511 | 1.00 | 13.46 | D | C |
| ATOM | 4634 | CB | ILE | D | 692 | 35.828 | 69.937 | 69.568 | 1.00 | 13.27 | D | C |
| ATOM | 4635 | CG2 | ILE | D | 692 | 36.742 | 70.852 | 70.372 | 1.00 | 12.87 | D | C |
| ATOM | 4636 | CG1 | ILE | D | 692 | 35.703 | 70.452 | 68.139 | 1.00 | 16.35 | D | C |
| ATOM | 4637 | CD1 | ILE | D | 692 | 35.159 | 71.848 | 68.032 | 1.00 | 17.73 | D | C |
| ATOM | 4638 | C | ILE | D | 692 | 36.920 | 68.058 | 70.889 | 1.00 | 15.47 | D | C |
| ATOM | 4639 | O | ILE | D | 692 | 36.225 | 67.382 | 71.658 | 1.00 | 14.67 | D | O |
| ATOM | 4640 | N | SER | D | 693 | 38.165 | 68.417 | 71.201 | 1.00 | 15.20 | D | N |
| ATOM | 4641 | CA | SER | D | 693 | 38.770 | 67.988 | 72.468 | 1.00 | 17.77 | D | C |
| ATOM | 4642 | CB | SER | D | 693 | 40.251 | 68.360 | 72.510 | 1.00 | 15.07 | D | C |
| ATOM | 4643 | OG | SER | D | 693 | 40.399 | 69.742 | 72.747 | 1.00 | 16.84 | D | O |
| ATOM | 4644 | C | SER | D | 693 | 38.084 | 68.553 | 73.699 | 1.00 | 17.99 | D | C |
| ATOM | 4645 | O | SER | D | 693 | 37.493 | 69.635 | 73.656 | 1.00 | 16.51 | D | O |
| ATOM | 4646 | N | HIS | D | 694 | 38.172 | 67.806 | 74.800 | 1.00 | 22.43 | D | N |
| ATOM | 4647 | CA | HIS | D | 694 | 37.574 | 68.222 | 76.069 | 1.00 | 23.25 | D | C |
| ATOM | 4648 | CB | HIS | D | 694 | 37.850 | 67.191 | 77.172 | 1.00 | 25.13 | D | C |
| ATOM | 4649 | CG | HIS | D | 694 | 37.329 | 67.599 | 78.516 | 1.00 | 26.41 | D | C |
| ATOM | 4650 | CD2 | HIS | D | 694 | 36.062 | 67.716 | 78.984 | 1.00 | 28.11 | D | C |
| ATOM | 4651 | ND1 | HIS | D | 694 | 38.153 | 68.013 | 79.539 | 1.00 | 28.55 | D | N |
| ATOM | 4652 | CE1 | HIS | D | 694 | 37.418 | 68.370 | 80.579 | 1.00 | 26.68 | D | C |
| ATOM | 4653 | NE2 | HIS | D | 694 | 36.146 | 68.199 | 80.268 | 1.00 | 25.47 | D | N |
| ATOM | 4654 | C | HIS | D | 694 | 38.096 | 69.581 | 76.522 | 1.00 | 22.44 | D | C |
| ATOM | 4655 | O | HIS | D | 694 | 37.335 | 70.419 | 76.998 | 1.00 | 23.33 | D | O |
| ATOM | 4656 | N | GLU | D | 695 | 39.394 | 69.800 | 76.363 | 1.00 | 23.23 | D | N |
| ATOM | 4657 | CA | GLU | D | 695 | 40.004 | 71.060 | 76.766 | 1.00 | 26.43 | D | C |
| ATOM | 4658 | CB | GLU | D | 695 | 41.526 | 71.012 | 76.540 | 1.00 | 33.47 | D | C |
| ATOM | 4659 | CG | GLU | D | 695 | 42.273 | 72.291 | 76.979 | 1.00 | 47.37 | D | C |
| ATOM | 4660 | CD | GLU | D | 695 | 43.239 | 72.885 | 75.910 | 1.00 | 54.84 | D | C |
| ATOM | 4661 | OE1 | GLU | D | 695 | 44.433 | 72.489 | 75.899 | 1.00 | 57.18 | D | O |
| ATOM | 4662 | OE2 | GLU | D | 695 | 42.814 | 73.757 | 75.096 | 1.00 | 56.02 | D | O |
| ATOM | 4663 | C | GLU | D | 695 | 39.412 | 72.246 | 76.014 | 1.00 | 24.52 | D | C |
| ATOM | 4664 | O | GLU | D | 695 | 39.159 | 73.300 | 76.599 | 1.00 | 23.71 | D | O |
| ATOM | 4665 | N | GLU | D | 696 | 39.183 | 72.083 | 74.716 | 1.00 | 22.69 | D | N |
| ATOM | 4666 | CA | GLU | D | 696 | 38.635 | 73.183 | 73.938 | 1.00 | 20.98 | D | C |
| ATOM | 4667 | CB | GLU | D | 696 | 38.854 | 72.940 | 72.456 | 1.00 | 22.69 | D | C |
| ATOM | 4668 | CG | GLU | D | 696 | 40.278 | 73.208 | 72.035 | 1.00 | 27.51 | D | C |
| ATOM | 4669 | CD | GLU | D | 696 | 40.610 | 72.546 | 70.718 | 1.00 | 36.33 | D | C |
| ATOM | 4670 | OE1 | GLU | D | 696 | 40.524 | 73.256 | 69.679 | 1.00 | 37.26 | D | O |
| ATOM | 4671 | OE2 | GLU | D | 696 | 40.944 | 71.324 | 70.720 | 1.00 | 35.11 | D | O |
| ATOM | 4672 | C | GLU | D | 696 | 37.165 | 73.401 | 74.209 | 1.00 | 18.80 | D | C |
| ATOM | 4673 | O | GLU | D | 696 | 36.698 | 74.540 | 74.242 | 1.00 | 16.92 | D | O |
| ATOM | 4674 | N | LYS | D | 697 | 36.431 | 72.313 | 74.401 | 1.00 | 17.55 | D | N |
| ATOM | 4675 | CA | LYS | D | 697 | 35.012 | 72.436 | 74.690 | 1.00 | 19.61 | D | C |
| ATOM | 4676 | CB | LYS | D | 697 | 34.363 | 71.065 | 74.753 | 1.00 | 17.52 | D | C |
| ATOM | 4677 | CG | LYS | D | 697 | 34.103 | 70.472 | 73.399 | 1.00 | 17.85 | D | C |
| ATOM | 4678 | CD | LYS | D | 697 | 33.199 | 69.273 | 73.527 | 1.00 | 17.99 | D | C |
| ATOM | 4679 | CE | LYS | D | 697 | 33.117 | 68.508 | 72.225 | 1.00 | 15.97 | D | C |
| ATOM | 4680 | NZ | LYS | D | 697 | 32.166 | 67.381 | 72.361 | 1.00 | 17.66 | D | N |
| ATOM | 4681 | C | LYS | D | 697 | 34.786 | 73.174 | 76.013 | 1.00 | 21.75 | D | C |
| ATOM | 4682 | O | LYS | D | 697 | 33.898 | 74.032 | 76.104 | 1.00 | 22.43 | D | O |
| ATOM | 4683 | N | ALA | D | 698 | 35.583 | 72.844 | 77.031 | 1.00 | 21.17 | D | N |
| ATOM | 4684 | CA | ALA | D | 698 | 35.451 | 73.495 | 78.328 | 1.00 | 21.88 | D | C |
| ATOM | 4685 | CB | ALA | D | 698 | 36.482 | 72.933 | 79.319 | 1.00 | 20.65 | D | C |
| ATOM | 4686 | C | ALA | D | 698 | 35.682 | 74.978 | 78.111 | 1.00 | 21.41 | D | C |
| ATOM | 4687 | O | ALA | D | 698 | 35.067 | 75.823 | 78.756 | 1.00 | 22.92 | D | O |
| ATOM | 4688 | N | LYS | D | 699 | 36.570 | 75.287 | 77.177 | 1.00 | 22.78 | D | N |
| ATOM | 4689 | CA | LYS | D | 699 | 36.907 | 76.667 | 76.844 | 1.00 | 22.90 | D | C |
| ATOM | 4690 | CB | LYS | D | 699 | 38.158 | 76.687 | 75.965 | 1.00 | 25.25 | D | C |
| ATOM | 4691 | CG | LYS | D | 699 | 38.543 | 78.061 | 75.464 | 1.00 | 29.23 | D | C |
| ATOM | 4692 | CD | LYS | D | 699 | 39.851 | 78.007 | 74.670 | 1.00 | 34.34 | D | C |
| ATOM | 4693 | CE | LYS | D | 699 | 39.754 | 78.791 | 73.360 | 1.00 | 34.42 | D | C |
| ATOM | 4694 | NZ | LYS | D | 699 | 39.643 | 80.257 | 73.597 | 1.00 | 34.98 | D | N |
| ATOM | 4695 | C | LYS | D | 699 | 35.781 | 77.428 | 76.137 | 1.00 | 22.15 | D | C |
| ATOM | 4696 | O | LYS | D | 699 | 35.549 | 78.597 | 76.420 | 1.00 | 22.23 | D | O |
| ATOM | 4697 | N | PHE | D | 700 | 35.089 | 76.767 | 75.212 | 1.00 | 21.09 | D | N |
| ATOM | 4698 | CA | PHE | D | 700 | 33.992 | 77.392 | 74.462 | 1.00 | 18.29 | D | C |
| ATOM | 4699 | CB | PHE | D | 700 | 33.719 | 76.630 | 73.149 | 1.00 | 15.77 | D | C |
| ATOM | 4700 | CG | PHE | D | 700 | 34.925 | 76.464 | 72.267 | 1.00 | 18.18 | D | C |
| ATOM | 4701 | CD1 | PHE | D | 700 | 35.917 | 77.441 | 72.226 | 1.00 | 15.06 | D | C |
| ATOM | 4702 | CD2 | PHE | D | 700 | 35.058 | 75.331 | 71.448 | 1.00 | 16.02 | D | C |
| ATOM | 4703 | CE1 | PHE | D | 700 | 37.029 | 77.301 | 71.379 | 1.00 | 13.83 | D | C |
| ATOM | 4704 | CE2 | PHE | D | 700 | 36.164 | 75.179 | 70.599 | 1.00 | 15.32 | D | C |
| ATOM | 4705 | CZ | PHE | D | 700 | 37.153 | 76.175 | 70.567 | 1.00 | 13.17 | D | C |
| ATOM | 4706 | C | PHE | D | 700 | 32.681 | 77.425 | 75.232 | 1.00 | 16.84 | D | C |
| ATOM | 4707 | O | PHE | D | 700 | 31.916 | 78.371 | 75.101 | 1.00 | 16.20 | D | O |
| ATOM | 4708 | N | LEU | D | 701 | 32.428 | 76.376 | 76.014 | 1.00 | 16.64 | D | N |
| ATOM | 4709 | CA | LEU | D | 701 | 31.176 | 76.222 | 76.753 | 1.00 | 17.23 | D | C |
| ATOM | 4710 | CB | LEU | D | 701 | 30.622 | 74.824 | 76.481 | 1.00 | 13.41 | D | C |
| ATOM | 4711 | CG | LEU | D | 701 | 30.411 | 74.401 | 75.028 | 1.00 | 13.42 | D | C |
| ATOM | 4712 | CD1 | LEU | D | 701 | 29.878 | 72.971 | 75.017 | 1.00 | 13.65 | D | C |
| ATOM | 4713 | CD2 | LEU | D | 701 | 29.439 | 75.343 | 74.330 | 1.00 | 8.23 | D | C |
| ATOM | 4714 | C | LEU | D | 701 | 31.190 | 76.437 | 78.273 | 1.00 | 20.02 | D | C |
| ATOM | 4715 | O | LEU | D | 701 | 30.129 | 76.649 | 78.881 | 1.00 | 19.05 | D | O |
| ATOM | 4716 | N | GLY | D | 702 | 32.374 | 76.370 | 78.874 | 1.00 | 20.70 | D | N |
| ATOM | 4717 | CA | GLY | D | 702 | 32.500 | 76.510 | 80.314 | 1.00 | 22.60 | D | C |
| ATOM | 4718 | C | GLY | D | 702 | 33.007 | 75.190 | 80.883 | 1.00 | 25.69 | D | C |
| ATOM | 4719 | O | GLY | D | 702 | 32.712 | 74.109 | 80.341 | 1.00 | 25.51 | D | O |
| ATOM | 4720 | N | ASN | D | 703 | 33.752 | 75.260 | 81.982 | 1.00 | 24.85 | D | N |
| ATOM | 4721 | CA | ASN | D | 703 | 34.328 | 74.061 | 82.587 | 1.00 | 25.88 | D | C |
| ATOM | 4722 | CB | ASN | D | 703 | 35.251 | 74.470 | 83.735 | 1.00 | 29.81 | D | C |
| ATOM | 4723 | CG | ASN | D | 703 | 36.468 | 75.234 | 83.251 | 1.00 | 34.59 | D | C |
| ATOM | 4724 | OD1 | ASN | D | 703 | 37.240 | 74.747 | 82.416 | 1.00 | 36.97 | D | O |
| ATOM | 4725 | ND2 | ASN | D | 703 | 36.646 | 76.443 | 83.771 | 1.00 | 36.38 | D | N |
| ATOM | 4726 | C | ASN | D | 703 | 33.388 | 72.956 | 83.066 | 1.00 | 24.40 | D | C |
| ATOM | 4727 | O | ASN | D | 703 | 33.803 | 71.805 | 83.200 | 1.00 | 25.74 | D | O |
| ATOM | 4728 | N | ASN | D | 704 | 32.128 | 73.283 | 83.315 | 1.00 | 21.40 | D | N |
| ATOM | 4729 | CA | ASN | D | 704 | 31.191 | 72.276 | 83.792 | 1.00 | 22.88 | D | C |
| ATOM | 4730 | CB | ASN | D | 704 | 30.407 | 72.852 | 84.966 | 1.00 | 28.48 | D | C |
| ATOM | 4731 | CG | ASN | D | 704 | 30.599 | 72.052 | 86.229 | 1.00 | 37.31 | D | C |
| ATOM | 4732 | OD1 | ASN | D | 704 | 29.789 | 71.174 | 86.557 | 1.00 | 39.95 | D | O |
| ATOM | 4733 | ND2 | ASN | D | 704 | 31.684 | 72.341 | 86.950 | 1.00 | 40.62 | D | N |
| ATOM | 4734 | C | ASN | D | 704 | 30.216 | 71.780 | 82.716 | 1.00 | 21.25 | D | C |
| ATOM | 4735 | O | ASN | D | 704 | 29.192 | 71.163 | 83.023 | 1.00 | 16.05 | D | O |
| ATOM | 4736 | N | TYR | D | 705 | 30.551 | 72.044 | 81.458 | 1.00 | 19.45 | D | N |
| ATOM | 4737 | CA | TYR | D | 705 | 29.700 | 71.677 | 80.335 | 1.00 | 19.55 | D | C |
| ATOM | 4738 | CB | TYR | D | 705 | 30.389 | 72.072 | 79.023 | 1.00 | 18.23 | D | C |
| ATOM | 4739 | CG | TYR | D | 705 | 31.396 | 71.071 | 78.524 | 1.00 | 17.24 | D | C |
| ATOM | 4740 | CD1 | TYR | D | 705 | 32.737 | 71.164 | 78.882 | 1.00 | 16.50 | D | C |
| ATOM | 4741 | CE1 | TYR | D | 705 | 33.659 | 70.219 | 78.444 | 1.00 | 16.64 | D | C |
| ATOM | 4742 | CD2 | TYR | D | 705 | 31.000 | 70.009 | 77.709 | 1.00 | 16.59 | D | C |
| ATOM | 4743 | CE2 | TYR | D | 705 | 31.910 | 69.065 | 77.269 | 1.00 | 15.52 | D | C |
| ATOM | 4744 | CZ | TYR | D | 705 | 33.234 | 69.173 | 77.642 | 1.00 | 16.31 | D | C |
| ATOM | 4745 | OH | TYR | D | 705 | 34.126 | 68.208 | 77.247 | 1.00 | 19.45 | D | O |
| ATOM | 4746 | C | TYR | D | 705 | 29.230 | 70.220 | 80.267 | 1.00 | 20.12 | D | C |
| ATOM | 4747 | O | TYR | D | 705 | 28.215 | 69.932 | 79.633 | 1.00 | 20.93 | D | O |
| ATOM | 4748 | N | LEU | D | 706 | 29.944 | 69.303 | 80.913 | 1.00 | 19.68 | D | N |
| ATOM | 4749 | CA | LEU | D | 706 | 29.547 | 67.895 | 80.888 | 1.00 | 20.58 | D | C |
| ATOM | 4750 | CB | LEU | D | 706 | 30.747 | 67.003 | 81.214 | 1.00 | 21.67 | D | C |
| ATOM | 4751 | CG | LEU | D | 706 | 31.722 | 66.738 | 80.065 | 1.00 | 23.08 | D | C |
| ATOM | 4752 | CD1 | LEU | D | 706 | 33.024 | 66.161 | 80.602 | 1.00 | 22.30 | D | C |
| ATOM | 4753 | CD2 | LEU | D | 706 | 31.073 | 65.775 | 79.082 | 1.00 | 23.26 | D | C |
| ATOM | 4754 | C | LEU | D | 706 | 28.389 | 67.584 | 81.850 | 1.00 | 22.26 | D | C |
| ATOM | 4755 | O | LEU | D | 706 | 27.798 | 66.501 | 81.801 | 1.00 | 20.52 | D | O |
| ATOM | 4756 | N | GLU | D | 707 | 28.074 | 68.538 | 82.722 | 1.00 | 23.68 | D | N |
| ATOM | 4757 | CA | GLU | D | 707 | 26.986 | 68.379 | 83.681 | 1.00 | 23.56 | D | C |
| ATOM | 4758 | CB | GLU | D | 707 | 27.222 | 69.293 | 84.891 | 1.00 | 27.14 | D | C |
| ATOM | 4759 | CG | GLU | D | 707 | 28.361 | 68.840 | 85.791 | 1.00 | 33.16 | D | C |
| ATOM | 4760 | CD | GLU | D | 707 | 28.393 | 67.329 | 85.957 | 1.00 | 39.92 | D | C |
| ATOM | 4761 | OE1 | GLU | D | 707 | 29.460 | 66.712 | 85.705 | 1.00 | 40.62 | D | O |
| ATOM | 4762 | OE2 | GLU | D | 707 | 27.343 | 66.756 | 86.330 | 1.00 | 41.00 | D | O |
| ATOM | 4763 | C | GLU | D | 707 | 25.687 | 68.764 | 82.985 | 1.00 | 22.39 | D | C |
| ATOM | 4764 | O | GLU | D | 707 | 25.625 | 69.764 | 82.276 | 1.00 | 21.91 | D | O |
| ATOM | 4765 | N | GLU | D | 708 | 24.644 | 67.980 | 83.195 | 1.00 | 20.20 | D | N |
| ATOM | 4766 | CA | GLU | D | 708 | 23.366 | 68.264 | 82.563 | 1.00 | 22.80 | D | C |
| ATOM | 4767 | CB | GLU | D | 708 | 22.600 | 66.945 | 82.360 | 1.00 | 24.19 | D | C |
| ATOM | 4768 | CG | GLU | D | 708 | 23.514 | 65.729 | 82.496 | 1.00 | 29.76 | D | C |
| ATOM | 4769 | CD | GLU | D | 708 | 23.148 | 64.567 | 81.594 | 1.00 | 29.61 | D | C |
| ATOM | 4770 | OE1 | GLU | D | 708 | 21.951 | 64.273 | 81.467 | 1.00 | 30.92 | D | O |
| ATOM | 4771 | OE2 | GLU | D | 708 | 24.063 | 63.927 | 81.018 | 1.00 | 34.57 | D | O |
| ATOM | 4772 | C | GLU | D | 708 | 22.520 | 69.303 | 83.323 | 1.00 | 21.92 | D | C |
| ATOM | 4773 | O | GLU | D | 708 | 22.624 | 69.459 | 84.543 | 1.00 | 19.70 | D | O |
| ATOM | 4774 | N | GLY | D | 709 | 21.697 | 70.030 | 82.573 | 1.00 | 20.62 | D | N |
| ATOM | 4775 | CA | GLY | D | 709 | 20.842 | 71.036 | 83.173 | 1.00 | 16.88 | D | C |
| ATOM | 4776 | C | GLY | D | 709 | 21.558 | 72.366 | 83.275 | 1.00 | 16.65 | D | C |
| ATOM | 4777 | O | GLY | D | 709 | 22.676 | 72.504 | 82.771 | 1.00 | 16.52 | D | O |
| ATOM | 4778 | N | PRO | D | 710 | 20.938 | 73.361 | 83.926 | 1.00 | 14.11 | D | N |
| ATOM | 4779 | CD | PRO | D | 710 | 19.594 | 73.231 | 84.518 | 1.00 | 13.65 | D | C |
| ATOM | 4780 | CA | PRO | D | 710 | 21.483 | 74.707 | 84.113 | 1.00 | 14.32 | D | C |
| ATOM | 4781 | CB | PRO | D | 710 | 20.433 | 75.399 | 84.978 | 1.00 | 12.65 | D | C |
| ATOM | 4782 | CG | PRO | D | 710 | 19.168 | 74.647 | 84.696 | 1.00 | 13.73 | D | C |
| ATOM | 4783 | C | PRO | D | 710 | 22.866 | 74.754 | 84.735 | 1.00 | 16.32 | D | C |
| ATOM | 4784 | O | PRO | D | 710 | 23.647 | 75.675 | 84.466 | 1.00 | 17.73 | D | O |
| ATOM | 4785 | N | ILE | D | 711 | 23.177 | 73.766 | 85.565 | 1.00 | 15.72 | D | N |
| ATOM | 4786 | CA | ILE | D | 711 | 24.475 | 73.730 | 86.214 | 1.00 | 18.41 | D | C |
| ATOM | 4787 | CB | ILE | D | 711 | 24.529 | 72.591 | 87.296 | 1.00 | 19.06 | D | C |
| ATOM | 4788 | CG2 | ILE | D | 711 | 24.895 | 71.254 | 86.669 | 1.00 | 18.62 | D | C |
| ATOM | 4789 | CG1 | ILE | D | 711 | 25.565 | 72.937 | 88.370 | 1.00 | 23.00 | D | C |
| ATOM | 4790 | CD1 | ILE | D | 711 | 25.415 | 74.348 | 88.979 | 1.00 | 22.00 | D | C |
| ATOM | 4791 | C | ILE | D | 711 | 25.604 | 73.566 | 85.185 | 1.00 | 17.91 | D | C |
| ATOM | 4792 | O | ILE | D | 711 | 26.732 | 74.015 | 85.406 | 1.00 | 20.11 | D | O |
| ATOM | 4793 | N | GLY | D | 712 | 25.300 | 72.937 | 84.057 | 1.00 | 16.50 | D | N |
| ATOM | 4794 | CA | GLY | D | 712 | 26.310 | 72.746 | 83.031 | 1.00 | 17.32 | D | C |
| ATOM | 4795 | C | GLY | D | 712 | 26.462 | 73.917 | 82.070 | 1.00 | 15.71 | D | C |
| ATOM | 4796 | O | GLY | D | 712 | 27.385 | 73.949 | 81.273 | 1.00 | 18.88 | D | O |
| ATOM | 4797 | N | ASN | D | 713 | 25.574 | 74.896 | 82.148 | 1.00 | 13.96 | D | N |
| ATOM | 4798 | CA | ASN | D | 713 | 25.645 | 76.032 | 81.241 | 1.00 | 13.48 | D | C |
| ATOM | 4799 | CB | ASN | D | 713 | 24.237 | 76.388 | 80.733 | 1.00 | 11.33 | D | C |
| ATOM | 4800 | CG | ASN | D | 713 | 24.250 | 77.532 | 79.734 | 1.00 | 12.66 | D | C |
| ATOM | 4801 | OD1 | ASN | D | 713 | 23.482 | 78.500 | 79.854 | 1.00 | 15.14 | D | O |
| ATOM | 4802 | ND2 | ASN | D | 713 | 25.121 | 77.432 | 78.743 | 1.00 | 7.78 | D | N |
| ATOM | 4803 | C | ASN | D | 713 | 26.275 | 77.279 | 81.830 | 1.00 | 14.21 | D | C |
| ATOM | 4804 | O | ASN | D | 713 | 25.900 | 77.714 | 82.917 | 1.00 | 17.28 | D | O |
| ATOM | 4805 | N | ASP | D | 714 | 27.223 | 77.851 | 81.099 | 1.00 | 13.37 | D | N |
| ATOM | 4806 | CA | ASP | D | 714 | 27.889 | 79.089 | 81.491 | 1.00 | 14.31 | D | C |
| ATOM | 4807 | CB | ASP | D | 714 | 29.415 | 78.893 | 81.487 | 1.00 | 17.58 | D | C |
| ATOM | 4808 | CG | ASP | D | 714 | 30.182 | 80.141 | 81.942 | 1.00 | 20.93 | D | C |
| ATOM | 4809 | OD1 | ASP | D | 714 | 29.560 | 81.232 | 82.049 | 1.00 | 21.58 | D | O |
| ATOM | 4810 | OD2 | ASP | D | 714 | 31.413 | 80.026 | 82.187 | 1.00 | 18.87 | D | O |
| ATOM | 4811 | C | ASP | D | 714 | 27.481 | 80.113 | 80.419 | 1.00 | 15.31 | D | C |
| ATOM | 4812 | O | ASP | D | 714 | 28.106 | 80.183 | 79.359 | 1.00 | 13.63 | D | O |
| ATOM | 4813 | N | ILE | D | 715 | 26.441 | 80.899 | 80.700 | 1.00 | 12.36 | D | N |
| ATOM | 4814 | CA | ILE | D | 715 | 25.933 | 81.877 | 79.750 | 1.00 | 14.43 | D | C |
| ATOM | 4815 | CB | ILE | D | 715 | 24.715 | 82.653 | 80.337 | 1.00 | 15.74 | D | C |
| ATOM | 4816 | CG2 | ILE | D | 715 | 25.172 | 83.606 | 81.439 | 1.00 | 17.14 | D | C |
| ATOM | 4817 | CG1 | ILE | D | 715 | 24.018 | 83.461 | 79.237 | 1.00 | 12.94 | D | C |
| ATOM | 4818 | CD1 | ILE | D | 715 | 22.795 | 84.187 | 79.711 | 1.00 | 9.84 | D | C |
| ATOM | 4819 | C | ILE | D | 715 | 26.978 | 82.875 | 79.285 | 1.00 | 15.45 | D | C |
| ATOM | 4820 | O | ILE | D | 715 | 26.876 | 83.430 | 78.194 | 1.00 | 16.52 | D | O |
| ATOM | 4821 | N | ARG | D | 716 | 27.981 | 83.121 | 80.109 | 1.00 | 16.17 | D | N |
| ATOM | 4822 | CA | ARG | D | 716 | 29.001 | 84.069 | 79.724 | 1.00 | 18.20 | D | C |
| ATOM | 4823 | CB | ARG | D | 716 | 29.976 | 84.308 | 80.868 | 1.00 | 20.48 | D | C |
| ATOM | 4824 | CG | ARG | D | 716 | 29.471 | 85.280 | 81.927 | 1.00 | 29.35 | D | C |
| ATOM | 4825 | CD | ARG | D | 716 | 30.293 | 85.164 | 83.218 | 1.00 | 36.12 | D | C |
| ATOM | 4826 | NE | ARG | D | 716 | 30.613 | 83.770 | 83.527 | 1.00 | 43.62 | D | N |
| ATOM | 4827 | CZ | ARG | D | 716 | 31.591 | 83.373 | 84.337 | 1.00 | 46.36 | D | C |
| ATOM | 4828 | NH1 | ARG | D | 716 | 32.371 | 84.262 | 84.944 | 1.00 | 45.23 | D | N |
| ATOM | 4829 | NH2 | ARG | D | 716 | 31.788 | 82.076 | 84.540 | 1.00 | 48.63 | D | N |
| ATOM | 4830 | C | ARG | D | 716 | 29.752 | 83.538 | 78.519 | 1.00 | 19.76 | D | C |
| ATOM | 4831 | O | ARG | D | 716 | 30.395 | 84.314 | 77.804 | 1.00 | 19.54 | D | O |
| ATOM | 4832 | N | LYS | D | 717 | 29.664 | 82.225 | 78.284 | 1.00 | 18.00 | D | N |
| ATOM | 4833 | CA | LYS | D | 717 | 30.354 | 81.607 | 77.155 | 1.00 | 17.27 | D | C |
| ATOM | 4834 | CB | LYS | D | 717 | 31.165 | 80.400 | 77.645 | 1.00 | 18.93 | D | C |
| ATOM | 4835 | CG | LYS | D | 717 | 32.457 | 80.802 | 78.357 | 1.00 | 19.42 | D | C |
| ATOM | 4836 | CD | LYS | D | 717 | 33.206 | 79.618 | 78.896 | 1.00 | 24.15 | D | C |
| ATOM | 4837 | CE | LYS | D | 717 | 34.647 | 80.009 | 79.234 | 1.00 | 29.33 | D | C |
| ATOM | 4838 | NZ | LYS | D | 717 | 35.355 | 78.948 | 80.037 | 1.00 | 31.96 | D | N |
| ATOM | 4839 | C | LYS | D | 717 | 29.443 | 81.174 | 76.001 | 1.00 | 17.07 | D | C |
| ATOM | 4840 | O | LYS | D | 717 | 29.830 | 81.231 | 74.832 | 1.00 | 16.90 | D | O |
| ATOM | 4841 | N | THR | D | 718 | 28.228 | 80.766 | 76.336 | 1.00 | 15.49 | D | N |
| ATOM | 4842 | CA | THR | D | 718 | 27.273 | 80.255 | 75.359 | 1.00 | 13.88 | D | C |
| ATOM | 4843 | CB | THR | D | 718 | 26.603 | 78.994 | 75.913 | 1.00 | 12.64 | D | C |
| ATOM | 4844 | OG1 | THR | D | 718 | 25.702 | 79.369 | 76.966 | 1.00 | 15.50 | D | O |
| ATOM | 4845 | CG2 | THR | D | 718 | 27.649 | 78.028 | 76.466 | 1.00 | 12.61 | D | C |
| ATOM | 4846 | C | THR | D | 718 | 26.154 | 81.203 | 74.920 | 1.00 | 15.83 | D | C |
| ATOM | 4847 | O | THR | D | 718 | 25.565 | 81.011 | 73.858 | 1.00 | 14.58 | D | O |
| ATOM | 4848 | N | ASN | D | 719 | 25.850 | 82.210 | 75.738 | 1.00 | 14.39 | D | N |
| ATOM | 4849 | CA | ASN | D | 719 | 24.760 | 83.141 | 75.449 | 1.00 | 12.27 | D | C |
| ATOM | 4850 | CB | ASN | D | 719 | 24.994 | 83.911 | 74.149 | 1.00 | 12.04 | D | C |
| ATOM | 4851 | CG | ASN | D | 719 | 24.267 | 85.236 | 74.136 | 1.00 | 13.34 | D | C |
| ATOM | 4852 | OD1 | ASN | D | 719 | 24.390 | 86.021 | 75.070 | 1.00 | 17.85 | D | O |
| ATOM | 4853 | ND2 | ASN | D | 719 | 23.497 | 85.496 | 73.084 | 1.00 | 13.96 | D | N |
| ATOM | 4854 | C | ASN | D | 719 | 23.401 | 82.436 | 75.373 | 1.00 | 14.00 | D | C |
| ATOM | 4855 | O | ASN | D | 719 | 22.475 | 82.906 | 74.702 | 1.00 | 14.40 | D | O |
| ATOM | 4856 | N | VAL | D | 720 | 23.289 | 81.297 | 76.045 | 1.00 | 14.52 | D | N |
| ATOM | 4857 | CA | VAL | D | 720 | 22.030 | 80.558 | 76.109 | 1.00 | 12.81 | D | C |
| ATOM | 4858 | CB | VAL | D | 720 | 22.260 | 79.001 | 76.070 | 1.00 | 14.77 | D | C |
| ATOM | 4859 | CG1 | VAL | D | 720 | 20.938 | 78.276 | 76.355 | 1.00 | 12.54 | D | C |
| ATOM | 4860 | CG2 | VAL | D | 720 | 22.825 | 78.559 | 74.697 | 1.00 | 7.63 | D | C |
| ATOM | 4861 | C | VAL | D | 720 | 21.415 | 80.931 | 77.469 | 1.00 | 13.27 | D | C |
| ATOM | 4862 | O | VAL | D | 720 | 22.085 | 80.852 | 78.490 | 1.00 | 15.06 | D | O |
| ATOM | 4863 | N | ALA | D | 721 | 20.151 | 81.345 | 77.477 | 1.00 | 12.65 | D | N |
| ATOM | 4864 | CA | ALA | D | 721 | 19.463 | 81.729 | 78.714 | 1.00 | 12.32 | D | C |
| ATOM | 4865 | CB | ALA | D | 721 | 18.062 | 82.246 | 78.388 | 1.00 | 11.26 | D | C |
| ATOM | 4866 | C | ALA | D | 721 | 19.363 | 80.585 | 79.712 | 1.00 | 10.58 | D | C |
| ATOM | 4867 | O | ALA | D | 721 | 19.140 | 79.443 | 79.333 | 1.00 | 13.19 | D | O |
| ATOM | 4868 | N | GLN | D | 722 | 19.518 | 80.887 | 80.996 | 1.00 | 11.63 | D | N |
| ATOM | 4869 | CA | GLN | D | 722 | 19.413 | 79.842 | 82.010 | 1.00 | 12.28 | D | C |
| ATOM | 4870 | CB | GLN | D | 722 | 19.938 | 80.355 | 83.366 | 1.00 | 12.42 | D | C |
| ATOM | 4871 | CG | GLN | D | 722 | 21.453 | 80.311 | 83.491 | 1.00 | 10.46 | D | C |
| ATOM | 4872 | CD | GLN | D | 722 | 22.006 | 78.892 | 83.401 | 1.00 | 17.17 | D | C |
| ATOM | 4873 | OE1 | GLN | D | 722 | 22.574 | 78.361 | 84.360 | 1.00 | 20.73 | D | O |
| ATOM | 4874 | NE2 | GLN | D | 722 | 21.844 | 78.271 | 82.246 | 1.00 | 17.00 | D | N |
| ATOM | 4875 | C | GLN | D | 722 | 17.937 | 79.411 | 82.095 | 1.00 | 11.10 | D | C |
| ATOM | 4876 | O | GLN | D | 722 | 17.624 | 78.273 | 82.476 | 1.00 | 9.92 | D | O |
| ATOM | 4877 | N | ILE | D | 723 | 17.033 | 80.319 | 81.726 | 1.00 | 10.86 | D | N |
| ATOM | 4878 | CA | ILE | D | 723 | 15.600 | 80.008 | 81.713 | 1.00 | 11.43 | D | C |
| ATOM | 4879 | CB | ILE | D | 723 | 14.773 | 81.239 | 81.259 | 1.00 | 11.73 | D | C |
| ATOM | 4880 | CG2 | ILE | D | 723 | 13.365 | 80.817 | 80.853 | 1.00 | 12.31 | D | C |
| ATOM | 4881 | CG1 | ILE | D | 723 | 14.671 | 82.252 | 82.396 | 1.00 | 11.35 | D | C |
| ATOM | 4882 | CD1 | ILE | D | 723 | 14.021 | 83.576 | 81.981 | 1.00 | 6.70 | D | C |
| ATOM | 4883 | C | ILE | D | 723 | 15.373 | 78.858 | 80.711 | 1.00 | 13.18 | D | C |
| ATOM | 4884 | O | ILE | D | 723 | 14.582 | 77.929 | 80.952 | 1.00 | 11.89 | D | O |
| ATOM | 4885 | N | ARG | D | 724 | 16.075 | 78.931 | 79.579 | 1.00 | 11.77 | D | N |
| ATOM | 4886 | CA | ARG | D | 724 | 15.959 | 77.907 | 78.539 | 1.00 | 9.64 | D | C |
| ATOM | 4887 | CB | ARG | D | 724 | 16.738 | 78.355 | 77.277 | 1.00 | 11.03 | D | C |
| ATOM | 4888 | CG | ARG | D | 724 | 16.614 | 77.437 | 76.041 | 1.00 | 9.68 | D | C |
| ATOM | 4889 | CD | ARG | D | 724 | 15.152 | 77.088 | 75.716 | 1.00 | 10.04 | D | C |
| ATOM | 4890 | NE | ARG | D | 724 | 14.411 | 78.227 | 75.163 | 1.00 | 13.29 | D | N |
| ATOM | 4891 | CZ | ARG | D | 724 | 14.420 | 78.571 | 73.871 | 1.00 | 13.91 | D | C |
| ATOM | 4892 | NH1 | ARG | D | 724 | 15.130 | 77.865 | 72.989 | 1.00 | 9.00 | D | N |
| ATOM | 4893 | NH2 | ARG | D | 724 | 13.746 | 79.635 | 73.461 | 1.00 | 9.49 | D | N |
| ATOM | 4894 | C | ARG | D | 724 | 16.520 | 76.599 | 79.095 | 1.00 | 8.09 | D | C |
| ATOM | 4895 | O | ARG | D | 724 | 15.902 | 75.550 | 78.961 | 1.00 | 8.27 | D | O |
| ATOM | 4896 | N | MET | D | 725 | 17.676 | 76.663 | 79.747 | 1.00 | 7.84 | D | N |
| ATOM | 4897 | CA | MET | D | 725 | 18.286 | 75.457 | 80.294 | 1.00 | 9.53 | D | C |
| ATOM | 4898 | CB | MET | D | 725 | 19.624 | 75.783 | 80.963 | 1.00 | 5.79 | D | C |
| ATOM | 4899 | CG | MET | D | 725 | 20.708 | 76.268 | 80.038 | 1.00 | 6.91 | D | C |
| ATOM | 4900 | SD | MET | D | 725 | 21.222 | 75.057 | 78.809 | 1.00 | 14.77 | D | S |
| ATOM | 4901 | CE | MET | D | 725 | 21.653 | 73.604 | 79.808 | 1.00 | 11.94 | D | C |
| ATOM | 4902 | C | MET | D | 725 | 17.371 | 74.777 | 81.306 | 1.00 | 11.85 | D | C |
| ATOM | 4903 | O | MET | D | 725 | 17.173 | 73.552 | 81.266 | 1.00 | 14.63 | D | O |
| ATOM | 4904 | N | ALA | D | 726 | 16.814 | 75.575 | 82.213 | 1.00 | 13.50 | D | N |
| ATOM | 4905 | CA | ALA | D | 726 | 15.906 | 75.066 | 83.247 | 1.00 | 13.75 | D | C |
| ATOM | 4906 | CB | ALA | D | 726 | 15.509 | 76.204 | 84.220 | 1.00 | 8.27 | D | C |
| ATOM | 4907 | C | ALA | D | 726 | 14.661 | 74.459 | 82.630 | 1.00 | 12.08 | D | C |
| ATOM | 4908 | O | ALA | D | 726 | 14.194 | 73.397 | 83.062 | 1.00 | 12.87 | D | O |
| ATOM | 4909 | N | TYR | D | 727 | 14.106 | 75.144 | 81.633 | 1.00 | 11.15 | D | N |
| ATOM | 4910 | CA | TYR | D | 727 | 12.911 | 74.632 | 80.978 | 1.00 | 10.89 | D | C |
| ATOM | 4911 | CB | TYR | D | 727 | 12.418 | 75.590 | 79.871 | 1.00 | 10.05 | D | C |
| ATOM | 4912 | CG | TYR | D | 727 | 11.302 | 74.970 | 79.039 | 1.00 | 10.67 | D | C |
| ATOM | 4913 | CD1 | TYR | D | 727 | 11.584 | 74.277 | 77.861 | 1.00 | 11.76 | D | C |
| ATOM | 4914 | CE1 | TYR | D | 727 | 10.562 | 73.644 | 77.128 | 1.00 | 12.56 | D | C |
| ATOM | 4915 | CD2 | TYR | D | 727 | 9.973 | 75.021 | 79.462 | 1.00 | 11.29 | D | C |
| ATOM | 4916 | CE2 | TYR | D | 727 | 8.947 | 74.394 | 78.739 | 1.00 | 11.79 | D | C |
| ATOM | 4917 | CZ | TYR | D | 727 | 9.253 | 73.706 | 77.575 | 1.00 | 11.83 | D | C |
| ATOM | 4918 | OH | TYR | D | 727 | 8.250 | 73.069 | 76.876 | 1.00 | 12.50 | D | O |
| ATOM | 4919 | C | TYR | D | 727 | 13.155 | 73.248 | 80.374 | 1.00 | 10.93 | D | C |
| ATOM | 4920 | O | TYR | D | 727 | 12.367 | 72.332 | 80.582 | 1.00 | 8.58 | D | O |
| ATOM | 4921 | N | ARG | D | 728 | 14.254 | 73.091 | 79.637 | 1.00 | 11.97 | D | N |
| ATOM | 4922 | CA | ARG | D | 728 | 14.541 | 71.808 | 78.994 | 1.00 | 9.64 | D | C |
| ATOM | 4923 | CB | ARG | D | 728 | 15.778 | 71.910 | 78.096 | 1.00 | 8.75 | D | C |
| ATOM | 4924 | CG | ARG | D | 728 | 15.657 | 72.919 | 76.980 | 1.00 | 10.91 | D | C |
| ATOM | 4925 | CD | ARG | D | 728 | 14.665 | 72.472 | 75.899 | 1.00 | 10.99 | D | C |
| ATOM | 4926 | NE | ARG | D | 728 | 14.813 | 73.273 | 74.674 | 1.00 | 12.23 | D | N |
| ATOM | 4927 | CZ | ARG | D | 728 | 13.943 | 73.276 | 73.675 | 1.00 | 11.84 | D | C |
| ATOM | 4928 | NH1 | ARG | D | 728 | 12.856 | 72.521 | 73.747 | 1.00 | 8.94 | D | N |
| ATOM | 4929 | NH2 | ARG | D | 728 | 14.159 | 74.036 | 72.605 | 1.00 | 11.81 | D | N |
| ATOM | 4930 | C | ARG | D | 728 | 14.775 | 70.709 | 80.001 | 1.00 | 11.09 | D | C |
| ATOM | 4931 | O | ARG | D | 728 | 14.260 | 69.600 | 79.862 | 1.00 | 10.79 | D | O |
| ATOM | 4932 | N | TYR | D | 729 | 15.579 | 71.015 | 81.013 | 1.00 | 12.28 | D | N |
| ATOM | 4933 | CA | TYR | D | 729 | 15.907 | 70.030 | 82.036 | 1.00 | 11.24 | D | C |
| ATOM | 4934 | CB | TYR | D | 729 | 16.897 | 70.644 | 83.020 | 1.00 | 12.02 | D | C |
| ATOM | 4935 | CG | TYR | D | 729 | 17.494 | 69.651 | 83.980 | 1.00 | 16.39 | D | C |
| ATOM | 4936 | CD1 | TYR | D | 729 | 18.141 | 68.504 | 83.525 | 1.00 | 11.35 | D | C |
| ATOM | 4937 | CE1 | TYR | D | 729 | 18.699 | 67.603 | 84.422 | 1.00 | 17.06 | D | C |
| ATOM | 4938 | CD2 | TYR | D | 729 | 17.416 | 69.872 | 85.356 | 1.00 | 18.42 | D | C |
| ATOM | 4939 | CE2 | TYR | D | 729 | 17.965 | 68.983 | 86.261 | 1.00 | 18.65 | D | C |
| ATOM | 4940 | CZ | TYR | D | 729 | 18.604 | 67.853 | 85.797 | 1.00 | 20.33 | D | C |
| ATOM | 4941 | OH | TYR | D | 729 | 19.135 | 66.989 | 86.733 | 1.00 | 22.21 | D | O |
| ATOM | 4942 | C | TYR | D | 729 | 14.668 | 69.532 | 82.755 | 1.00 | 8.41 | D | C |
| ATOM | 4943 | O | TYR | D | 729 | 14.439 | 68.331 | 82.895 | 1.00 | 10.49 | D | O |
| ATOM | 4944 | N | GLU | D | 730 | 13.843 | 70.462 | 83.192 | 1.00 | 10.24 | D | N |
| ATOM | 4945 | CA | GLU | D | 730 | 12.627 | 70.092 | 83.888 | 1.00 | 12.07 | D | C |
| ATOM | 4946 | CB | GLU | D | 730 | 11.919 | 71.355 | 84.395 | 1.00 | 10.30 | D | C |
| ATOM | 4947 | CG | GLU | D | 730 | 12.780 | 72.206 | 85.311 | 1.00 | 13.76 | D | C |
| ATOM | 4948 | CD | GLU | D | 730 | 12.147 | 73.553 | 85.644 | 1.00 | 17.24 | D | C |
| ATOM | 4949 | OE1 | GLU | D | 730 | 12.811 | 74.384 | 86.303 | 1.00 | 17.97 | D | O |
| ATOM | 4950 | OE2 | GLU | D | 730 | 10.987 | 73.791 | 85.253 | 1.00 | 18.56 | D | O |
| ATOM | 4951 | C | GLU | D | 730 | 11.669 | 69.270 | 83.015 | 1.00 | 13.33 | D | C |
| ATOM | 4952 | O | GLU | D | 730 | 11.122 | 68.259 | 83.476 | 1.00 | 15.28 | D | O |
| ATOM | 4953 | N | THR | D | 731 | 11.460 | 69.669 | 81.757 | 1.00 | 13.26 | D | N |
| ATOM | 4954 | CA | THR | D | 731 | 10.515 | 68.907 | 80.958 | 1.00 | 12.96 | D | C |
| ATOM | 4955 | CB | THR | D | 731 | 9.947 | 69.741 | 79.743 | 1.00 | 15.90 | D | C |
| ATOM | 4956 | OG1 | THR | D | 731 | 10.435 | 69.226 | 78.508 | 1.00 | 20.79 | D | O |
| ATOM | 4957 | CG2 | THR | D | 731 | 10.282 | 71.206 | 79.876 | 1.00 | 5.13 | D | C |
| ATOM | 4958 | C | THR | D | 731 | 11.076 | 67.543 | 80.574 | 1.00 | 11.40 | D | C |
| ATOM | 4959 | O | THR | D | 731 | 10.320 | 66.587 | 80.444 | 1.00 | 11.64 | D | O |
| ATOM | 4960 | N | TRP | D | 732 | 12.400 | 67.432 | 80.460 | 1.00 | 10.29 | D | N |
| ATOM | 4961 | CA | TRP | D | 732 | 13.042 | 66.148 | 80.155 | 1.00 | 9.33 | D | C |
| ATOM | 4962 | CB | TRP | D | 732 | 14.516 | 66.380 | 79.825 | 1.00 | 8.28 | D | C |
| ATOM | 4963 | CG | TRP | D | 732 | 15.322 | 65.158 | 79.479 | 1.00 | 6.38 | D | C |
| ATOM | 4964 | CD2 | TRP | D | 732 | 16.739 | 65.001 | 79.641 | 1.00 | 8.93 | D | C |
| ATOM | 4965 | CE2 | TRP | D | 732 | 17.086 | 63.741 | 79.104 | 1.00 | 8.03 | D | C |
| ATOM | 4966 | CE3 | TRP | D | 732 | 17.751 | 65.806 | 80.185 | 1.00 | 9.47 | D | C |
| ATOM | 4967 | CD1 | TRP | D | 732 | 14.878 | 64.017 | 78.878 | 1.00 | 7.01 | D | C |
| ATOM | 4968 | NE1 | TRP | D | 732 | 15.933 | 63.159 | 78.645 | 1.00 | 7.58 | D | N |
| ATOM | 4969 | CZ2 | TRP | D | 732 | 18.406 | 63.266 | 79.092 | 1.00 | 10.58 | D | C |
| ATOM | 4970 | CZ3 | TRP | D | 732 | 19.065 | 65.333 | 80.170 | 1.00 | 11.29 | D | C |
| ATOM | 4971 | CH2 | TRP | D | 732 | 19.377 | 64.074 | 79.625 | 1.00 | 9.82 | D | C |
| ATOM | 4972 | C | TRP | D | 732 | 12.907 | 65.204 | 81.371 | 1.00 | 10.97 | D | C |
| ATOM | 4973 | O | TRP | D | 732 | 12.539 | 64.037 | 81.234 | 1.00 | 10.26 | D | O |
| ATOM | 4974 | N | CYS | D | 733 | 13.189 | 65.718 | 82.565 | 1.00 | 12.18 | D | N |
| ATOM | 4975 | CA | CYS | D | 733 | 13.064 | 64.909 | 83.792 | 1.00 | 12.80 | D | C |
| ATOM | 4976 | CB | CYS | D | 733 | 13.526 | 65.715 | 85.011 | 1.00 | 10.30 | D | C |
| ATOM | 4977 | SG | CYS | D | 733 | 15.326 | 65.920 | 85.125 | 1.00 | 18.32 | D | S |
| ATOM | 4978 | C | CYS | D | 733 | 11.613 | 64.467 | 83.991 | 1.00 | 11.81 | D | C |
| ATOM | 4979 | O | CYS | D | 733 | 11.335 | 63.327 | 84.368 | 1.00 | 12.32 | D | O |
| ATOM | 4980 | N | TYR | D | 734 | 10.682 | 65.371 | 83.723 | 1.00 | 10.36 | D | N |
| ATOM | 4981 | CA | TYR | D | 734 | 9.285 | 65.034 | 83.871 | 1.00 | 11.32 | D | C |
| ATOM | 4982 | CB | TYR | D | 734 | 8.429 | 66.227 | 83.461 | 1.00 | 12.26 | D | C |
| ATOM | 4983 | CG | TYR | D | 734 | 6.983 | 66.067 | 83.834 | 1.00 | 17.25 | D | C |
| ATOM | 4984 | CD1 | TYR | D | 734 | 6.507 | 66.558 | 85.036 | 1.00 | 18.46 | D | C |
| ATOM | 4985 | CE1 | TYR | D | 734 | 5.178 | 66.416 | 85.396 | 1.00 | 22.10 | D | C |
| ATOM | 4986 | CD2 | TYR | D | 734 | 6.088 | 65.419 | 82.989 | 1.00 | 21.57 | D | C |
| ATOM | 4987 | CE2 | TYR | D | 734 | 4.750 | 65.269 | 83.340 | 1.00 | 25.22 | D | C |
| ATOM | 4988 | CZ | TYR | D | 734 | 4.305 | 65.776 | 84.551 | 1.00 | 24.56 | D | C |
| ATOM | 4989 | OH | TYR | D | 734 | 2.981 | 65.674 | 84.914 | 1.00 | 30.31 | D | O |
| ATOM | 4990 | C | TYR | D | 734 | 8.907 | 63.803 | 83.036 | 1.00 | 11.69 | D | C |
| ATOM | 4991 | O | TYR | D | 734 | 8.253 | 62.887 | 83.525 | 1.00 | 10.83 | D | O |
| ATOM | 4992 | N | GLU | D | 735 | 9.321 | 63.771 | 81.775 | 1.00 | 11.04 | D | N |
| ATOM | 4993 | CA | GLU | D | 735 | 8.968 | 62.643 | 80.918 | 1.00 | 11.49 | D | C |
| ATOM | 4994 | CB | GLU | D | 735 | 9.423 | 62.909 | 79.472 | 1.00 | 10.85 | D | C |
| ATOM | 4995 | CG | GLU | D | 735 | 8.720 | 64.079 | 78.788 | 1.00 | 9.11 | D | C |
| ATOM | 4996 | CD | GLU | D | 735 | 7.209 | 63.929 | 78.784 | 1.00 | 8.78 | D | C |
| ATOM | 4997 | OE1 | GLU | D | 735 | 6.697 | 62.880 | 78.344 | 1.00 | 11.56 | D | O |
| ATOM | 4998 | OE2 | GLU | D | 735 | 6.526 | 64.865 | 79.226 | 1.00 | 11.40 | D | O |
| ATOM | 4999 | C | GLU | D | 735 | 9.568 | 61.332 | 81.428 | 1.00 | 11.12 | D | C |
| ATOM | 5000 | O | GLU | D | 735 | 8.914 | 60.291 | 81.408 | 1.00 | 10.00 | D | O |
| ATOM | 5001 | N | LEU | D | 736 | 10.817 | 61.383 | 81.877 | 1.00 | 12.16 | D | N |
| ATOM | 5002 | CA | LEU | D | 736 | 11.488 | 60.182 | 82.385 | 1.00 | 14.48 | D | C |
| ATOM | 5003 | CB | LEU | D | 736 | 12.969 | 60.482 | 82.668 | 1.00 | 11.56 | D | C |
| ATOM | 5004 | CG | LEU | D | 736 | 13.881 | 60.731 | 81.459 | 1.00 | 12.92 | D | C |
| ATOM | 5005 | CD1 | LEU | D | 736 | 15.168 | 61.428 | 81.914 | 1.00 | 7.76 | D | C |
| ATOM | 5006 | CD2 | LEU | D | 736 | 14.201 | 59.410 | 80.758 | 1.00 | 7.55 | D | C |
| ATOM | 5007 | C | LEU | D | 736 | 10.800 | 59.701 | 83.667 | 1.00 | 15.89 | D | C |
| ATOM | 5008 | O | LEU | D | 736 | 10.652 | 58.502 | 83.905 | 1.00 | 17.44 | D | O |
| ATOM | 5009 | N | ASN | D | 737 | 10.382 | 60.645 | 84.497 | 1.00 | 16.96 | D | N |
| ATOM | 5010 | CA | ASN | D | 737 | 9.709 | 60.300 | 85.728 | 1.00 | 17.61 | D | C |
| ATOM | 5011 | CB | ASN | D | 737 | 9.475 | 61.540 | 86.548 | 1.00 | 21.22 | D | C |
| ATOM | 5012 | CG | ASN | D | 737 | 9.038 | 61.210 | 87.937 | 1.00 | 24.65 | D | C |
| ATOM | 5013 | OD1 | ASN | D | 737 | 9.811 | 60.667 | 88.704 | 1.00 | 28.60 | D | O |
| ATOM | 5014 | ND2 | ASN | D | 737 | 7.789 | 61.515 | 88.268 | 1.00 | 24.38 | D | N |
| ATOM | 5015 | C | ASN | D | 737 | 8.377 | 59.610 | 85.482 | 1.00 | 20.43 | D | C |
| ATOM | 5016 | O | ASN | D | 737 | 7.955 | 58.754 | 86.265 | 1.00 | 22.12 | D | O |
| ATOM | 5017 | N | LEU | D | 738 | 7.701 | 59.979 | 84.402 | 1.00 | 18.72 | D | N |
| ATOM | 5018 | CA | LEU | D | 738 | 6.424 | 59.353 | 84.096 | 1.00 | 18.63 | D | C |
| ATOM | 5019 | CB | LEU | D | 738 | 5.847 | 59.912 | 82.793 | 1.00 | 18.53 | D | C |
| ATOM | 5020 | CG | LEU | D | 738 | 5.314 | 61.349 | 82.824 | 1.00 | 19.24 | D | C |
| ATOM | 5021 | CD1 | LEU | D | 738 | 4.833 | 61.758 | 81.426 | 1.00 | 14.86 | D | C |
| ATOM | 5022 | CD2 | LEU | D | 738 | 4.200 | 61.448 | 83.845 | 1.00 | 13.46 | D | C |
| ATOM | 5023 | C | LEU | D | 738 | 6.615 | 57.855 | 83.959 | 1.00 | 18.24 | D | C |
| ATOM | 5024 | O | LEU | D | 738 | 5.774 | 57.065 | 84.366 | 1.00 | 20.26 | D | O |
| ATOM | 5025 | N | ILE | D | 739 | 7.732 | 57.459 | 83.379 | 1.00 | 17.88 | D | N |
| ATOM | 5026 | CA | ILE | D | 739 | 7.979 | 56.047 | 83.182 | 1.00 | 17.84 | D | C |
| ATOM | 5027 | CB | ILE | D | 739 | 9.148 | 55.820 | 82.223 | 1.00 | 17.57 | D | C |
| ATOM | 5028 | CG2 | ILE | D | 739 | 9.546 | 54.346 | 82.248 | 1.00 | 11.94 | D | C |
| ATOM | 5029 | CG1 | ILE | D | 739 | 8.757 | 56.291 | 80.810 | 1.00 | 20.51 | D | C |
| ATOM | 5030 | CD1 | ILE | D | 739 | 9.922 | 56.780 | 79.978 | 1.00 | 20.87 | D | C |
| ATOM | 5031 | C | ILE | D | 739 | 8.285 | 55.383 | 84.506 | 1.00 | 19.67 | D | C |
| ATOM | 5032 | O | ILE | D | 739 | 7.814 | 54.271 | 84.774 | 1.00 | 17.54 | D | O |
| ATOM | 5033 | N | ALA | D | 740 | 9.077 | 56.073 | 85.330 | 1.00 | 20.75 | D | N |
| ATOM | 5034 | CA | ALA | D | 740 | 9.454 | 55.564 | 86.651 | 1.00 | 22.77 | D | C |
| ATOM | 5035 | CB | ALA | D | 740 | 10.412 | 56.529 | 87.333 | 1.00 | 20.84 | D | C |
| ATOM | 5036 | C | ALA | D | 740 | 8.207 | 55.352 | 87.517 | 1.00 | 21.26 | D | C |
| ATOM | 5037 | O | ALA | D | 740 | 8.058 | 54.318 | 88.164 | 1.00 | 20.82 | D | O |
| ATOM | 5038 | N | GLU | D | 741 | 7.306 | 56.323 | 87.512 | 1.00 | 19.63 | D | N |
| ATOM | 5039 | CA | GLU | D | 741 | 6.089 | 56.202 | 88.293 | 1.00 | 22.13 | D | C |
| ATOM | 5040 | CB | GLU | D | 741 | 5.297 | 57.503 | 88.235 | 1.00 | 22.45 | D | C |
| ATOM | 5041 | CG | GLU | D | 741 | 6.064 | 58.702 | 88.758 | 1.00 | 32.72 | D | C |
| ATOM | 5042 | CD | GLU | D | 741 | 6.018 | 58.795 | 90.278 | 1.00 | 36.02 | D | C |
| ATOM | 5043 | OE1 | GLU | D | 741 | 7.001 | 59.271 | 90.884 | 1.00 | 37.49 | D | O |
| ATOM | 5044 | OE2 | GLU | D | 741 | 4.992 | 58.386 | 90.866 | 1.00 | 39.52 | D | O |
| ATOM | 5045 | C | GLU | D | 741 | 5.216 | 55.064 | 87.785 | 1.00 | 23.14 | D | C |
| ATOM | 5046 | O | GLU | D | 741 | 4.588 | 54.363 | 88.575 | 1.00 | 21.04 | D | O |
| ATOM | 5047 | N | GLY | D | 742 | 5.167 | 54.893 | 86.465 | 1.00 | 23.85 | D | N |
| ATOM | 5048 | CA | GLY | D | 742 | 4.350 | 53.838 | 85.902 | 1.00 | 24.32 | D | C |
| ATOM | 5049 | C | GLY | D | 742 | 4.828 | 52.467 | 86.328 | 1.00 | 25.26 | D | C |
| ATOM | 5050 | O | GLY | D | 742 | 4.077 | 51.493 | 86.274 | 1.00 | 27.82 | D | O |
| ATOM | 5051 | N | LEU | D | 743 | 6.081 | 52.395 | 86.761 | 1.00 | 25.85 | D | N |
| ATOM | 5052 | CA | LEU | D | 743 | 6.696 | 51.140 | 87.183 | 1.00 | 25.98 | D | C |
| ATOM | 5053 | CB | LEU | D | 743 | 8.124 | 51.086 | 86.649 | 1.00 | 23.44 | D | C |
| ATOM | 5054 | CG | LEU | D | 743 | 8.447 | 50.391 | 85.325 | 1.00 | 24.73 | D | C |
| ATOM | 5055 | CD1 | LEU | D | 743 | 7.218 | 50.298 | 84.456 | 1.00 | 24.87 | D | C |
| ATOM | 5056 | CD2 | LEU | D | 743 | 9.567 | 51.139 | 84.637 | 1.00 | 21.05 | D | C |
| ATOM | 5057 | C | LEU | D | 743 | 6.733 | 50.975 | 88.708 | 1.00 | 30.68 | D | C |
| ATOM | 5058 | O | LEU | D | 743 | 6.923 | 49.880 | 89.220 | 1.00 | 34.79 | D | O |
| ATOM | 5059 | N | LYS | D | 744 | 6.558 | 52.079 | 89.422 | 1.00 | 34.25 | D | N |
| ATOM | 5060 | CA | LYS | D | 744 | 6.601 | 52.120 | 90.878 | 1.00 | 35.72 | D | C |
| ATOM | 5061 | CB | LYS | D | 744 | 6.289 | 53.537 | 91.334 | 1.00 | 33.53 | D | C |
| ATOM | 5062 | CG | LYS | D | 744 | 7.398 | 54.213 | 92.050 | 1.00 | 31.37 | D | C |
| ATOM | 5063 | CD | LYS | D | 744 | 6.814 | 55.085 | 93.116 | 1.00 | 35.28 | D | C |
| ATOM | 5064 | CE | LYS | D | 744 | 7.282 | 56.506 | 92.985 | 1.00 | 38.68 | D | C |
| ATOM | 5065 | NZ | LYS | D | 744 | 7.164 | 57.177 | 94.316 | 1.00 | 41.49 | D | N |
| ATOM | 5066 | C | LYS | D | 744 | 5.688 | 51.149 | 91.629 | 1.00 | 41.29 | D | C |
| ATOM | 5067 | O | LYS | D | 744 | 4.529 | 50.930 | 91.257 | 1.00 | 41.36 | D | O |
| ATOM | 5068 | N | SER | D | 745 | 6.228 | 50.591 | 92.710 | 1.00 | 45.87 | D | N |
| ATOM | 5069 | CA | SER | D | 745 | 5.500 | 49.655 | 93.557 | 1.00 | 51.39 | D | C |
| ATOM | 5070 | CB | SER | D | 745 | 5.251 | 48.346 | 92.797 | 1.00 | 52.22 | D | C |
| ATOM | 5071 | OG | SER | D | 745 | 3.932 | 47.877 | 93.017 | 1.00 | 56.77 | D | O |
| ATOM | 5072 | C | SER | D | 745 | 6.291 | 49.384 | 94.853 | 1.00 | 56.03 | D | C |
| ATOM | 5073 | O | SER | D | 745 | 6.904 | 48.291 | 94.968 | 1.00 | 59.59 | D | O |
| ATOM | 5074 | OT | SER | D | 745 | 6.293 | 50.271 | 95.747 | 1.00 | 57.67 | D | O |
| ATOM | 5075 | CB | SER | E | 106 | −10.958 | 60.158 | 13.296 | 1.00 | 37.99 | E | C |
| ATOM | 5076 | OG | SER | E | 106 | −11.885 | 59.309 | 13.952 | 1.00 | 41.76 | E | 0 |
| ATOM | 5077 | C | SER | E | 106 | −13.139 | 60.672 | 12.192 | 1.00 | 36.66 | E | C |
| ATOM | 5078 | O | SER | E | 106 | −13.816 | 61.522 | 12.784 | 1.00 | 36.95 | E | O |
| ATOM | 5079 | N | SER | E | 106 | −11.119 | 62.212 | 11.911 | 1.00 | 35.31 | E | N |
| ATOM | 5080 | CA | SER | E | 106 | −11.608 | 60.803 | 12.073 | 1.00 | 37.50 | E | C |
| ATOM | 5081 | N | PRO | E | 107 | −13.697 | 59.574 | 11.656 | 1.00 | 35.15 | E | N |
| ATOM | 5082 | CD | PRO | E | 107 | −12.978 | 58.464 | 11.008 | 1.00 | 31.79 | E | C |
| ATOM | 5083 | CA | PRO | E | 107 | −15.140 | 59.334 | 11.696 | 1.00 | 35.21 | E | C |
| ATOM | 5084 | CB | PRO | E | 107 | −15.292 | 57.949 | 11.061 | 1.00 | 33.67 | E | C |
| ATOM | 5085 | CG | PRO | E | 107 | −14.061 | 57.742 | 10.276 | 1.00 | 29.84 | E | C |
| ATOM | 5086 | C | PRO | E | 107 | −15.744 | 59.382 | 13.098 | 1.00 | 37.78 | E | C |
| ATOM | 5087 | O | PRO | E | 107 | −16.852 | 59.891 | 13.282 | 1.00 | 38.22 | E | O |
| ATOM | 5088 | N | THR | E | 108 | −15.013 | 58.857 | 14.081 | 1.00 | 38.32 | E | N |
| ATOM | 5089 | CA | THR | E | 108 | −15.491 | 58.808 | 15.465 | 1.00 | 37.55 | E | C |
| ATOM | 5090 | CB | THR | E | 108 | −14.542 | 57.956 | 16.343 | 1.00 | 37.94 | E | C |
| ATOM | 5091 | OG1 | THR | E | 108 | −13.353 | 58.700 | 16.635 | 1.00 | 39.95 | E | O |
| ATOM | 5092 | CG2 | THR | E | 108 | −14.160 | 56.670 | 15.615 | 1.00 | 36.83 | E | C |
| ATOM | 5093 | C | THR | E | 108 | −15.738 | 60.151 | 16.167 | 1.00 | 35.75 | E | C |
| ATOM | 5094 | O | THR | E | 108 | −16.411 | 60.199 | 17.205 | 1.00 | 38.56 | E | O |
| ATOM | 5095 | N | TYR | E | 109 | −15.222 | 61.241 | 15.611 | 1.00 | 33.16 | E | N |
| ATOM | 5096 | CA | TYR | E | 109 | −15.429 | 62.546 | 16.235 | 1.00 | 29.26 | E | C |
| ATOM | 5097 | CB | TYR | E | 109 | −14.204 | 63.431 | 16.022 | 1.00 | 28.25 | E | C |
| ATOM | 5098 | CG | TYR | E | 109 | −13.135 | 63.208 | 17.063 | 1.00 | 30.49 | E | C |
| ATOM | 5099 | CD1 | TYR | E | 109 | −12.699 | 61.914 | 17.380 | 1.00 | 32.77 | E | C |
| ATOM | 5100 | CE1 | TYR | E | 109 | −11.689 | 61.699 | 18.325 | 1.00 | 29.07 | E | C |
| ATOM | 5101 | CD2 | TYR | E | 109 | −12.540 | 64.282 | 17.721 | 1.00 | 26.99 | E | C |
| ATOM | 5102 | CE2 | TYR | E | 109 | −11.533 | 64.081 | 18.662 | 1.00 | 24.18 | E | C |
| ATOM | 5103 | CZ | TYR | E | 109 | −11.109 | 62.793 | 18.957 | 1.00 | 27.84 | E | C |
| ATOM | 5104 | OH | TYR | E | 109 | −10.079 | 62.604 | 19.853 | 1.00 | 30.06 | E | O |
| ATOM | 5105 | C | TYR | E | 109 | −16.671 | 63.268 | 15.731 | 1.00 | 27.52 | E | C |
| ATOM | 5106 | O | TYR | E | 109 | −16.847 | 64.457 | 15.990 | 1.00 | 24.66 | E | O |
| ATOM | 5107 | N | GLN | E | 110 | −17.539 | 62.549 | 15.025 | 1.00 | 27.03 | E | N |
| ATOM | 5108 | CA | GLN | E | 110 | −18.761 | 63.151 | 14.487 | 1.00 | 28.31 | E | C |
| ATOM | 5109 | CB | GLN | E | 110 | −19.578 | 62.107 | 13.700 | 1.00 | 29.52 | E | C |
| ATOM | 5110 | CG | GLN | E | 110 | −20.775 | 62.679 | 12.919 | 1.00 | 31.01 | E | C |
| ATOM | 5111 | CD | GLN | E | 110 | −20.351 | 63.598 | 11.773 | 1.00 | 32.24 | E | C |
| ATOM | 5112 | OE1 | GLN | E | 110 | −19.163 | 63.697 | 11.459 | 1.00 | 31.01 | E | O |
| ATOM | 5113 | NE2 | GLN | E | 110 | −21.323 | 64.270 | 11.144 | 1.00 | 28.68 | E | N |
| ATOM | 5114 | C | GLN | E | 110 | −19.593 | 63.670 | 15.645 | 1.00 | 27.21 | E | C |
| ATOM | 5115 | O | GLN | E | 110 | −20.408 | 64.586 | 15.499 | 1.00 | 25.55 | E | O |
| ATOM | 5116 | N | THR | E | 111 | −19.325 | 63.086 | 16.805 | 1.00 | 25.61 | E | N |
| ATOM | 5117 | CA | THR | E | 111 | −20.038 | 63.368 | 18.036 | 1.00 | 23.92 | E | C |
| ATOM | 5118 | CB | THR | E | 111 | −20.363 | 61.995 | 18.666 | 1.00 | 26.13 | E | C |
| ATOM | 5119 | OG1 | THR | E | 111 | −21.777 | 61.802 | 18.661 | 1.00 | 29.72 | E | O |
| ATOM | 5120 | CG2 | THR | E | 111 | −19.793 | 61.860 | 20.048 | 1.00 | 25.39 | E | C |
| ATOM | 5121 | C | THR | E | 111 | −19.295 | 64.292 | 19.024 | 1.00 | 22.48 | E | C |
| ATOM | 5122 | O | THR | E | 111 | −19.827 | 64.671 | 20.071 | 1.00 | 19.23 | E | O |
| ATOM | 5123 | N | VAL | E | 112 | −18.075 | 64.673 | 18.670 | 1.00 | 19.20 | E | N |
| ATOM | 5124 | CA | VAL | E | 112 | −17.248 | 65.515 | 19.530 | 1.00 | 16.56 | E | C |
| ATOM | 5125 | CB | VAL | E | 112 | −15.792 | 65.003 | 19.522 | 1.00 | 12.54 | E | C |
| ATOM | 5126 | CG1 | VAL | E | 112 | −14.928 | 65.834 | 20.468 | 1.00 | 12.42 | E | C |
| ATOM | 5127 | CG2 | VAL | E | 112 | −15.763 | 63.536 | 19.899 | 1.00 | 11.64 | E | C |
| ATOM | 5128 | C | VAL | E | 112 | −17.230 | 66.999 | 19.142 | 1.00 | 17.60 | E | C |
| ATOM | 5129 | O | VAL | E | 112 | −16.746 | 67.356 | 18.070 | 1.00 | 15.90 | E | O |
| ATOM | 5130 | N | PRO | E | 113 | −17.744 | 67.883 | 20.019 | 1.00 | 16.14 | E | N |
| ATOM | 5131 | CD | PRO | E | 113 | −18.349 | 67.589 | 21.327 | 1.00 | 15.50 | E | C |
| ATOM | 5132 | CA | PRO | E | 113 | −17.756 | 69.320 | 19.726 | 1.00 | 14.30 | E | C |
| ATOM | 5133 | CB | PRO | E | 113 | −18.432 | 69.943 | 20.948 | 1.00 | 15.13 | E | C |
| ATOM | 5134 | CG | PRO | E | 113 | −19.162 | 68.825 | 21.602 | 1.00 | 14.03 | E | C |
| ATOM | 5135 | C | PRO | E | 113 | −16.338 | 69.835 | 19.587 | 1.00 | 16.20 | E | C |
| ATOM | 5136 | O | PRO | E | 113 | −15.375 | 69.168 | 19.985 | 1.00 | 16.41 | E | O |
| ATOM | 5137 | N | ASP | E | 114 | −16.205 | 71.022 | 19.016 | 1.00 | 16.89 | E | N |
| ATOM | 5138 | CA | ASP | E | 114 | −14.892 | 71.633 | 18.877 | 1.00 | 19.46 | E | C |
| ATOM | 5139 | CB | ASP | E | 114 | −14.958 | 72.854 | 17.963 | 1.00 | 24.08 | E | C |
| ATOM | 5140 | CG | ASP | E | 114 | −15.167 | 72.489 | 16.499 | 1.00 | 33.32 | E | C |
| ATOM | 5141 | OD1 | ASP | E | 114 | −14.824 | 71.351 | 16.092 | 1.00 | 37.48 | E | O |
| ATOM | 5142 | OD2 | ASP | E | 114 | −15.677 | 73.352 | 15.747 | 1.00 | 36.51 | E | O |
| ATOM | 5143 | C | ASP | E | 114 | −14.468 | 72.111 | 20.263 | 1.00 | 19.67 | E | C |
| ATOM | 5144 | O | ASP | E | 114 | −15.311 | 72.327 | 21.129 | 1.00 | 21.53 | E | O |
| ATOM | 5145 | N | PHE | E | 115 | −13.167 | 72.259 | 20.475 | 1.00 | 16.56 | E | N |
| ATOM | 5146 | CA | PHE | E | 115 | −12.658 | 72.778 | 21.732 | 1.00 | 15.89 | E | C |
| ATOM | 5147 | CB | PHE | E | 115 | −12.847 | 71.770 | 22.897 | 1.00 | 13.90 | E | C |
| ATOM | 5148 | CG | PHE | E | 115 | −12.070 | 70.482 | 22.768 | 1.00 | 11.31 | E | C |
| ATOM | 5149 | CD1 | PHE | E | 115 | −12.625 | 69.377 | 22.132 | 1.00 | 14.14 | E | C |
| ATOM | 5150 | CD2 | PHE | E | 115 | −10.827 | 70.345 | 23.365 | 1.00 | 11.80 | E | C |
| ATOM | 5151 | CE1 | PHE | E | 115 | −11.954 | 68.151 | 22.097 | 1.00 | 11.28 | E | C |
| ATOM | 5152 | CE2 | PHE | E | 115 | −10.144 | 69.127 | 23.338 | 1.00 | 13.77 | E | C |
| ATOM | 5153 | CZ | PHE | E | 115 | −10.709 | 68.027 | 22.703 | 1.00 | 13.73 | E | C |
| ATOM | 5154 | C | PHE | E | 115 | −11.203 | 73.163 | 21.522 | 1.00 | 17.03 | E | C |
| ATOM | 5155 | O | PHE | E | 115 | −10.563 | 72.685 | 20.582 | 1.00 | 20.16 | E | O |
| ATOM | 5156 | N | GLN | E | 116 | −10.682 | 74.052 | 22.360 | 1.00 | 15.05 | E | N |
| ATOM | 5157 | CA | GLN | E | 116 | −9.301 | 74.480 | 22.219 | 1.00 | 14.19 | E | C |
| ATOM | 5158 | CB | GLN | E | 116 | −9.086 | 75.808 | 22.943 | 1.00 | 13.58 | E | C |
| ATOM | 5159 | CG | GLN | E | 116 | −10.088 | 76.857 | 22.542 | 1.00 | 16.85 | E | C |
| ATOM | 5160 | CD | GLN | E | 116 | −9.752 | 78.232 | 23.082 | 1.00 | 21.35 | E | C |
| ATOM | 5161 | OE1 | GLN | E | 116 | −10.271 | 78.645 | 24.118 | 1.00 | 21.20 | E | O |
| ATOM | 5162 | NE2 | GLN | E | 116 | −8.879 | 78.954 | 22.375 | 1.00 | 22.26 | E | N |
| ATOM | 5163 | C | GLN | E | 116 | −8.336 | 73.428 | 22.751 | 1.00 | 14.82 | E | C |
| ATOM | 5164 | O | GLN | E | 116 | −8.480 | 72.915 | 23.867 | 1.00 | 16.44 | E | O |
| ATOM | 5165 | N | ARG | E | 117 | −7.340 | 73.108 | 21.945 | 1.00 | 13.28 | E | N |
| ATOM | 5166 | CA | ARG | E | 117 | −6.367 | 72.129 | 22.351 | 1.00 | 13.85 | E | C |
| ATOM | 5167 | CB | ARG | E | 117 | −6.217 | 71.076 | 21.271 | 1.00 | 14.53 | E | C |
| ATOM | 5168 | CG | ARG | E | 117 | −7.263 | 69.996 | 21.360 | 1.00 | 17.02 | E | C |
| ATOM | 5169 | CD | ARG | E | 117 | −7.853 | 69.782 | 20.008 | 1.00 | 21.00 | E | C |
| ATOM | 5170 | NE | ARG | E | 117 | −8.567 | 68.520 | 19.918 | 1.00 | 20.11 | E | N |
| ATOM | 5171 | CZ | ARG | E | 117 | −9.808 | 68.425 | 19.469 | 1.00 | 20.71 | E | C |
| ATOM | 5172 | NH1 | ARG | E | 117 | −10.442 | 69.521 | 19.081 | 1.00 | 22.69 | E | N |
| ATOM | 5173 | NH2 | ARG | E | 117 | −10.406 | 67.245 | 19.390 | 1.00 | 20.69 | E | N |
| ATOM | 5174 | C | ARG | E | 117 | −5.030 | 72.766 | 22.627 | 1.00 | 13.66 | E | C |
| ATOM | 5175 | O | ARG | E | 117 | −4.718 | 73.838 | 22.108 | 1.00 | 13.48 | E | O |
| ATOM | 5176 | N | VAL | E | 118 | −4.237 | 72.125 | 23.467 | 1.00 | 13.32 | E | N |
| ATOM | 5177 | CA | VAL | E | 118 | −2.931 | 72.670 | 23.728 | 1.00 | 16.88 | E | C |
| ATOM | 5178 | CB | VAL | E | 118 | −2.582 | 72.737 | 25.275 | 1.00 | 19.32 | E | C |
| ATOM | 5179 | CG1 | VAL | E | 118 | −3.755 | 72.255 | 26.119 | 1.00 | 17.76 | E | C |
| ATOM | 5180 | CG2 | VAL | E | 118 | −1.305 | 71.980 | 25.573 | 1.00 | 17.82 | E | C |
| ATOM | 5181 | C | VAL | E | 118 | −1.949 | 71.799 | 22.975 | 1.00 | 18.26 | E | C |
| ATOM | 5182 | O | VAL | E | 118 | −1.908 | 70.577 | 23.143 | 1.00 | 18.31 | E | O |
| ATOM | 5183 | N | GLN | E | 119 | −1.172 | 72.423 | 22.105 | 1.00 | 20.65 | E | N |
| ATOM | 5184 | CA | GLN | E | 119 | −0.194 | 71.655 | 21.366 | 1.00 | 23.77 | E | C |
| ATOM | 5185 | CB | GLN | E | 119 | −0.571 | 71.542 | 19.892 | 1.00 | 26.99 | E | C |
| ATOM | 5186 | CG | GLN | E | 119 | −0.903 | 72.835 | 19.216 | 1.00 | 37.33 | E | C |
| ATOM | 5187 | CD | GLN | E | 119 | −1.077 | 72.647 | 17.712 | 1.00 | 45.80 | E | C |
| ATOM | 5188 | OE1 | GLN | E | 119 | −0.267 | 73.140 | 16.911 | 1.00 | 45.58 | E | O |
| ATOM | 5189 | NE2 | GLN | E | 119 | −2.133 | 71.921 | 17.322 | 1.00 | 43.57 | E | N |
| ATOM | 5190 | C | GLN | E | 119 | 1.182 | 72.254 | 21.525 | 1.00 | 21.76 | E | C |
| ATOM | 5191 | O | GLN | E | 119 | 1.353 | 73.463 | 21.680 | 1.00 | 21.62 | E | O |
| ATOM | 5192 | N | ILE | E | 120 | 2.163 | 71.370 | 21.508 | 1.00 | 20.62 | E | N |
| ATOM | 5193 | CA | ILE | E | 120 | 3.540 | 71.740 | 21.678 | 1.00 | 19.86 | E | C |
| ATOM | 5194 | CB | ILE | E | 120 | 4.211 | 70.798 | 22.710 | 1.00 | 18.39 | E | C |
| ATOM | 5195 | CG2 | ILE | E | 120 | 5.641 | 71.242 | 22.990 | 1.00 | 16.28 | E | C |
| ATOM | 5196 | CG1 | ILE | E | 120 | 3.365 | 70.737 | 23.990 | 1.00 | 15.70 | E | C |
| ATOM | 5197 | CD1 | ILE | E | 120 | 3.038 | 72.073 | 24.603 | 1.00 | 10.99 | E | C |
| ATOM | 5198 | C | ILE | E | 120 | 4.278 | 71.652 | 20.347 | 1.00 | 22.63 | E | C |
| ATOM | 5199 | O | ILE | E | 120 | 4.311 | 70.603 | 19.705 | 1.00 | 20.43 | E | O |
| ATOM | 5200 | N | THR | E | 121 | 4.873 | 72.768 | 19.942 | 1.00 | 24.65 | E | N |
| ATOM | 5201 | CA | THR | E | 121 | 5.634 | 72.816 | 18.698 | 1.00 | 27.14 | E | C |
| ATOM | 5202 | CB | THR | E | 121 | 5.591 | 74.214 | 18.060 | 1.00 | 23.03 | E | C |
| ATOM | 5203 | OG1 | THR | E | 121 | 6.559 | 75.039 | 18.697 | 1.00 | 27.39 | E | O |
| ATOM | 5204 | CG2 | THR | E | 121 | 4.236 | 74.846 | 18.209 | 1.00 | 22.85 | E | C |
| ATOM | 5205 | C | THR | E | 121 | 7.092 | 72.468 | 18.998 | 1.00 | 28.97 | E | C |
| ATOM | 5206 | O | THR | E | 121 | 7.521 | 72.506 | 20.148 | 1.00 | 32.23 | E | O |
| ATOM | 5207 | N | GLY | E | 122 | 7.850 | 72.106 | 17.973 | 1.00 | 31.30 | E | N |
| ATOM | 5208 | CA | GLY | E | 122 | 9.246 | 71.779 | 18.186 | 1.00 | 33.43 | E | C |
| ATOM | 5209 | C | GLY | E | 122 | 9.564 | 70.320 | 18.447 | 1.00 | 37.20 | E | C |
| ATOM | 5210 | O | GLY | E | 122 | 8.682 | 69.504 | 18.732 | 1.00 | 38.04 | E | O |
| ATOM | 5211 | N | ASP | E | 123 | 10.855 | 70.006 | 18.354 | 1.00 | 41.01 | E | N |
| ATOM | 5212 | CA | ASP | E | 123 | 11.364 | 68.653 | 18.557 | 1.00 | 44.88 | E | C |
| ATOM | 5213 | CB | ASP | E | 123 | 12.711 | 68.472 | 17.834 | 1.00 | 50.97 | E | C |
| ATOM | 5214 | CG | ASP | E | 123 | 12.674 | 68.943 | 16.383 | 1.00 | 57.17 | E | C |
| ATOM | 5215 | OD1 | ASP | E | 123 | 11.789 | 68.471 | 15.627 | 1.00 | 60.71 | E | O |
| ATOM | 5216 | OD2 | ASP | E | 123 | 13.531 | 69.782 | 16.001 | 1.00 | 59.90 | E | O |
| ATOM | 5217 | C | ASP | E | 123 | 11.562 | 68.367 | 20.036 | 1.00 | 44.69 | E | C |
| ATOM | 5218 | O | ASP | E | 123 | 12.067 | 69.212 | 20.781 | 1.00 | 44.10 | E | O |
| ATOM | 5219 | N | TYR | E | 124 | 11.181 | 67.166 | 20.460 | 1.00 | 45.58 | E | N |
| ATOM | 5220 | CA | TYR | E | 124 | 11.333 | 66.779 | 21.860 | 1.00 | 43.75 | E | C |
| ATOM | 5221 | CB | TYR | E | 124 | 10.392 | 65.614 | 22.188 | 1.00 | 39.33 | E | C |
| ATOM | 5222 | CG | TYR | E | 124 | 9.029 | 66.090 | 22.611 | 1.00 | 36.63 | E | C |
| ATOM | 5223 | CD1 | TYR | E | 124 | 7.978 | 66.135 | 21.699 | 1.00 | 34.65 | E | C |
| ATOM | 5224 | CE1 | TYR | E | 124 | 6.740 | 66.660 | 22.057 | 1.00 | 35.89 | E | C |
| ATOM | 5225 | CD2 | TYR | E | 124 | 8.808 | 66.576 | 23.903 | 1.00 | 34.55 | E | C |
| ATOM | 5226 | CE2 | TYR | E | 124 | 7.570 | 67.104 | 24.272 | 1.00 | 33.36 | E | C |
| ATOM | 5227 | CZ | TYR | E | 124 | 6.543 | 67.145 | 23.341 | 1.00 | 33.68 | E | C |
| ATOM | 5228 | OH | TYR | E | 124 | 5.327 | 67.683 | 23.676 | 1.00 | 31.96 | E | O |
| ATOM | 5229 | C | TYR | E | 124 | 12.778 | 66.406 | 22.194 | 1.00 | 44.34 | E | C |
| ATOM | 5230 | O | TYR | E | 124 | 13.264 | 65.367 | 21.690 | 1.00 | 45.78 | E | O |
| ATOM | 5231 | OT | TYR | E | 124 | 13.409 | 67.167 | 22.958 | 1.00 | 45.36 | E | O |
| ATOM | 5232 | CB | ASP | F | 132 | 20.354 | 58.803 | 26.446 | 1.00 | 51.58 | F | C |
| ATOM | 5233 | CG | ASP | F | 132 | 20.230 | 59.168 | 27.932 | 1.00 | 56.77 | F | C |
| ATOM | 5234 | OD1 | ASP | F | 132 | 19.648 | 60.237 | 28.243 | 1.00 | 60.14 | F | O |
| ATOM | 5235 | OD2 | ASP | F | 132 | 20.715 | 58.393 | 28.790 | 1.00 | 58.00 | F | O |
| ATOM | 5236 | C | ASP | F | 132 | 18.274 | 57.386 | 26.309 | 1.00 | 44.89 | F | C |
| ATOM | 5237 | O | ASP | F | 132 | 17.749 | 56.638 | 27.142 | 1.00 | 41.55 | F | O |
| ATOM | 5238 | N | ASP | F | 132 | 20.194 | 56.998 | 24.740 | 1.00 | 45.19 | F | N |
| ATOM | 5239 | CA | ASP | F | 132 | 19.800 | 57.404 | 26.129 | 1.00 | 46.83 | F | C |
| ATOM | 5240 | N | PHE | F | 133 | 17.570 | 58.222 | 25.543 | 1.00 | 43.05 | F | N |
| ATOM | 5241 | CA | PHE | F | 133 | 16.108 | 58.253 | 25.600 | 1.00 | 42.94 | F | C |
| ATOM | 5242 | CB | PHE | F | 133 | 15.531 | 59.341 | 24.682 | 1.00 | 38.71 | F | C |
| ATOM | 5243 | CG | PHE | F | 133 | 14.017 | 59.345 | 24.617 | 1.00 | 40.12 | F | C |
| ATOM | 5244 | CD1 | PHE | F | 133 | 13.357 | 59.651 | 23.426 | 1.00 | 39.84 | F | C |
| ATOM | 5245 | CD2 | PHE | F | 133 | 13.246 | 59.027 | 25.753 | 1.00 | 40.73 | F | C |
| ATOM | 5246 | CE1 | PHE | F | 133 | 11.943 | 59.642 | 23.364 | 1.00 | 40.76 | F | C |
| ATOM | 5247 | CE2 | PHE | F | 133 | 11.838 | 59.012 | 25.705 | 1.00 | 36.74 | F | C |
| ATOM | 5248 | CZ | PHE | F | 133 | 11.186 | 59.319 | 24.512 | 1.00 | 39.89 | F | C |
| ATOM | 5249 | C | PHE | F | 133 | 15.702 | 56.887 | 25.073 | 1.00 | 42.93 | F | C |
| ATOM | 5250 | O | PHE | F | 133 | 14.680 | 56.314 | 25.458 | 1.00 | 44.61 | F | O |
| ATOM | 5251 | N | GLU | F | 134 | 16.542 | 56.387 | 24.177 | 1.00 | 41.65 | F | N |
| ATOM | 5252 | CA | GLU | F | 134 | 16.357 | 55.101 | 23.554 | 1.00 | 40.96 | F | C |
| ATOM | 5253 | CB | GLU | F | 134 | 17.579 | 54.778 | 22.699 | 1.00 | 45.67 | F | C |
| ATOM | 5254 | CG | GLU | F | 134 | 17.245 | 54.310 | 21.296 | 1.00 | 52.45 | F | C |
| ATOM | 5255 | CD | GLU | F | 134 | 17.635 | 52.855 | 21.067 | 1.00 | 57.46 | F | C |
| ATOM | 5256 | OE1 | GLU | F | 134 | 18.652 | 52.410 | 21.651 | 1.00 | 59.40 | F | O |
| ATOM | 5257 | OE2 | GLU | F | 134 | 16.922 | 52.158 | 20.308 | 1.00 | 57.97 | F | O |
| ATOM | 5258 | C | GLU | F | 134 | 16.173 | 54.037 | 24.621 | 1.00 | 38.45 | F | C |
| ATOM | 5259 | O | GLU | F | 134 | 15.204 | 53.281 | 24.590 | 1.00 | 38.38 | F | O |
| ATOM | 5260 | N | ILE | F | 135 | 17.100 | 53.979 | 25.572 | 1.00 | 35.96 | F | N |
| ATOM | 5261 | CA | ILE | F | 135 | 17.006 | 52.979 | 26.622 | 1.00 | 33.40 | F | C |
| ATOM | 5262 | CB | ILE | F | 135 | 18.302 | 52.922 | 27.472 | 1.00 | 36.59 | F | C |
| ATOM | 5263 | CG2 | ILE | F | 135 | 19.518 | 53.147 | 26.569 | 1.00 | 36.50 | F | C |
| ATOM | 5264 | CG1 | ILE | F | 135 | 18.249 | 53.953 | 28.600 | 1.00 | 39.77 | F | C |
| ATOM | 5265 | CD1 | ILE | F | 135 | 18.064 | 53.345 | 29.991 | 1.00 | 41.78 | F | C |
| ATOM | 5266 | C | ILE | F | 135 | 15.799 | 53.235 | 27.514 | 1.00 | 31.03 | F | C |
| ATOM | 5267 | O | ILE | F | 135 | 15.217 | 52.300 | 28.064 | 1.00 | 30.94 | F | O |
| ATOM | 5268 | N | VAL | F | 136 | 15.414 | 54.500 | 27.658 | 1.00 | 27.21 | F | N |
| ATOM | 5269 | CA | VAL | F | 136 | 14.245 | 54.816 | 28.469 | 1.00 | 24.26 | F | C |
| ATOM | 5270 | CB | VAL | F | 136 | 14.087 | 56.337 | 28.665 | 1.00 | 19.85 | F | C |
| ATOM | 5271 | CG1 | VAL | F | 136 | 12.771 | 56.644 | 29.318 | 1.00 | 16.73 | F | C |
| ATOM | 5272 | CG2 | VAL | F | 136 | 15.209 | 56.857 | 29.509 | 1.00 | 19.60 | F | C |
| ATOM | 5273 | C | VAL | F | 136 | 13.006 | 54.261 | 27.760 | 1.00 | 24.24 | F | C |
| ATOM | 5274 | O | VAL | F | 136 | 12.187 | 53.581 | 28.373 | 1.00 | 24.37 | F | O |
| ATOM | 5275 | N | CYS | F | 137 | 12.892 | 54.541 | 26.463 | 1.00 | 22.57 | F | N |
| ATOM | 5276 | CA | CYS | F | 137 | 11.763 | 54.082 | 25.659 | 1.00 | 22.23 | F | C |
| ATOM | 5277 | CB | CYS | F | 137 | 11.911 | 54.611 | 24.236 | 1.00 | 22.90 | F | C |
| ATOM | 5278 | SG | CYS | F | 137 | 11.485 | 56.352 | 24.079 | 1.00 | 30.26 | F | S |
| ATOM | 5279 | C | CYS | F | 137 | 11.675 | 52.562 | 25.640 | 1.00 | 22.57 | F | C |
| ATOM | 5280 | O | CYS | F | 137 | 10.580 | 51.975 | 25.685 | 1.00 | 21.59 | F | O |
| ATOM | 5281 | N | LYS | F | 138 | 12.838 | 51.926 | 25.562 | 1.00 | 22.42 | F | N |
| ATOM | 5282 | CA | LYS | F | 138 | 12.916 | 50.475 | 25.540 | 1.00 | 23.75 | F | C |
| ATOM | 5283 | CB | LYS | F | 138 | 14.356 | 50.030 | 25.326 | 1.00 | 25.77 | F | C |
| ATOM | 5284 | CG | LYS | F | 138 | 14.715 | 49.828 | 23.866 | 1.00 | 35.47 | F | C |
| ATOM | 5285 | CD | LYS | F | 138 | 16.233 | 49.834 | 23.668 | 1.00 | 40.84 | F | C |
| ATOM | 5286 | CE | LYS | F | 138 | 16.614 | 49.621 | 22.204 | 1.00 | 44.26 | F | C |
| ATOM | 5287 | NZ | LYS | F | 138 | 17.225 | 48.273 | 21.965 | 1.00 | 45.21 | F | N |
| ATOM | 5288 | C | LYS | F | 138 | 12.410 | 49.908 | 26.859 | 1.00 | 21.95 | F | C |
| ATOM | 5289 | O | LYS | F | 138 | 11.711 | 48.896 | 26.873 | 1.00 | 21.36 | F | O |
| ATOM | 5290 | N | GLY | F | 139 | 12.766 | 50.573 | 27.958 | 1.00 | 18.94 | F | N |
| ATOM | 5291 | CA | GLY | F | 139 | 12.352 | 50.134 | 29.281 | 1.00 | 16.41 | F | C |
| ATOM | 5292 | C | GLY | F | 139 | 10.853 | 50.221 | 29.484 | 1.00 | 14.99 | F | C |
| ATOM | 5293 | O | GLY | F | 139 | 10.228 | 49.289 | 29.971 | 1.00 | 15.53 | F | O |
| ATOM | 5294 | N | LEU | F | 140 | 10.271 | 51.350 | 29.112 | 1.00 | 16.03 | F | N |
| ATOM | 5295 | CA | LEU | F | 140 | 8.838 | 51.540 | 29.256 | 1.00 | 15.42 | F | C |
| ATOM | 5296 | CB | LEU | F | 140 | 8.463 | 52.975 | 28.897 | 1.00 | 15.35 | F | C |
| ATOM | 5297 | CG | LEU | F | 140 | 9.019 | 54.043 | 29.845 | 1.00 | 16.14 | F | C |
| ATOM | 5298 | CD1 | LEU | F | 140 | 8.567 | 55.432 | 29.393 | 1.00 | 16.67 | F | C |
| ATOM | 5299 | CD2 | LEU | F | 140 | 8.533 | 53.778 | 31.257 | 1.00 | 13.02 | F | C |
| ATOM | 5300 | C | LEU | F | 140 | 8.119 | 50.562 | 28.348 | 1.00 | 16.61 | F | C |
| ATOM | 5301 | O | LEU | F | 140 | 7.031 | 50.088 | 28.672 | 1.00 | 14.39 | F | O |
| ATOM | 5302 | N | TYR | F | 141 | 8.737 | 50.255 | 27.209 | 1.00 | 16.54 | F | N |
| ATOM | 5303 | CA | TYR | F | 141 | 8.142 | 49.308 | 26.277 | 1.00 | 16.52 | F | C |
| ATOM | 5304 | CB | TYR | F | 141 | 8.958 | 49.236 | 24.975 | 1.00 | 16.85 | F | C |
| ATOM | 5305 | CG | TYR | F | 141 | 8.646 | 48.001 | 24.168 | 1.00 | 14.26 | F | C |
| ATOM | 5306 | CD1 | TYR | F | 141 | 9.455 | 46.876 | 24.252 | 1.00 | 17.37 | F | C |
| ATOM | 5307 | CE1 | TYR | F | 141 | 9.134 | 45.710 | 23.560 | 1.00 | 22.62 | F | C |
| ATOM | 5308 | CD2 | TYR | F | 141 | 7.508 | 47.940 | 23.365 | 1.00 | 15.78 | F | C |
| ATOM | 5309 | CE2 | TYR | F | 141 | 7.176 | 46.790 | 22.668 | 1.00 | 17.42 | F | C |
| ATOM | 5310 | CZ | TYR | F | 141 | 7.990 | 45.677 | 22.773 | 1.00 | 23.66 | F | C |
| ATOM | 5311 | OH | TYR | F | 141 | 7.645 | 44.516 | 22.119 | 1.00 | 29.59 | F | O |
| ATOM | 5312 | C | TYR | F | 141 | 8.099 | 47.921 | 26.915 | 1.00 | 15.16 | F | C |
| ATOM | 5313 | O | TYR | F | 141 | 7.062 | 47.261 | 26.935 | 1.00 | 14.17 | F | O |
| ATOM | 5314 | N | ARG | F | 142 | 9.236 | 47.472 | 27.429 | 1.00 | 13.92 | F | N |
| ATOM | 5315 | CA | ARG | F | 142 | 9.274 | 46.158 | 28.032 | 1.00 | 16.56 | F | C |
| ATOM | 5316 | CB | ARG | F | 142 | 10.707 | 45.793 | 28.448 | 1.00 | 17.88 | F | C |
| ATOM | 5317 | CG | ARG | F | 142 | 10.749 | 44.524 | 29.293 | 1.00 | 22.39 | F | C |
| ATOM | 5318 | CD | ARG | F | 142 | 12.046 | 43.721 | 29.233 | 1.00 | 22.64 | F | C |
| ATOM | 5319 | NE | ARG | F | 142 | 11.872 | 42.498 | 30.030 | 1.00 | 31.13 | F | N |
| ATOM | 5320 | CZ | ARG | F | 142 | 12.830 | 41.887 | 30.730 | 1.00 | 31.43 | F | C |
| ATOM | 5321 | NH1 | ARG | F | 142 | 14.061 | 42.378 | 30.741 | 1.00 | 31.44 | F | N |
| ATOM | 5322 | NH2 | ARG | F | 142 | 12.546 | 40.804 | 31.455 | 1.00 | 27.03 | F | N |
| ATOM | 5323 | C | ARG | F | 142 | 8.323 | 46.081 | 29.236 | 1.00 | 16.73 | F | C |
| ATOM | 5324 | O | ARG | F | 142 | 7.664 | 45.060 | 29.456 | 1.00 | 18.69 | F | O |
| ATOM | 5325 | N | ALA | F | 143 | 8.228 | 47.164 | 30.003 | 1.00 | 14.94 | F | N |
| ATOM | 5326 | CA | ALA | F | 143 | 7.346 | 47.171 | 31.167 | 1.00 | 13.49 | F | C |
| ATOM | 5327 | CB | ALA | F | 143 | 7.463 | 48.482 | 31.911 | 1.00 | 12.14 | F | C |
| ATOM | 5328 | C | ALA | F | 143 | 5.896 | 46.928 | 30.777 | 1.00 | 13.24 | F | C |
| ATOM | 5329 | O | ALA | F | 143 | 5.210 | 46.117 | 31.408 | 1.00 | 11.88 | F | O |
| ATOM | 5330 | N | LEU | F | 144 | 5.427 | 47.632 | 29.744 | 1.00 | 13.14 | F | N |
| ATOM | 5331 | CA | LEU | F | 144 | 4.048 | 47.481 | 29.275 | 1.00 | 12.74 | F | C |
| ATOM | 5332 | CB | LEU | F | 144 | 3.725 | 48.545 | 28.226 | 1.00 | 11.99 | F | C |
| ATOM | 5333 | CG | LEU | F | 144 | 3.506 | 49.953 | 28.782 | 1.00 | 15.32 | F | C |
| ATOM | 5334 | CD1 | LEU | F | 144 | 3.349 | 50.973 | 27.658 | 1.00 | 13.81 | F | C |
| ATOM | 5335 | CD2 | LEU | F | 144 | 2.268 | 49.942 | 29.678 | 1.00 | 15.19 | F | C |
| ATOM | 5336 | C | LEU | F | 144 | 3.818 | 46.088 | 28.695 | 1.00 | 14.69 | F | C |
| ATOM | 5337 | O | LEU | F | 144 | 2.716 | 45.537 | 28.794 | 1.00 | 14.71 | F | O |
| ATOM | 5338 | N | CYS | F | 145 | 4.859 | 45.518 | 28.095 | 1.00 | 15.55 | F | N |
| ATOM | 5339 | CA | CYS | F | 145 | 4.765 | 44.181 | 27.524 | 1.00 | 18.03 | F | C |
| ATOM | 5340 | CB | CYS | F | 145 | 6.012 | 43.860 | 26.709 | 1.00 | 24.84 | F | C |
| ATOM | 5341 | SG | CYS | F | 145 | 5.891 | 44.438 | 25.032 | 1.00 | 41.18 | F | S |
| ATOM | 5342 | C | CYS | F | 145 | 4.640 | 43.162 | 28.646 | 1.00 | 15.66 | F | C |
| ATOM | 5343 | O | CYS | F | 145 | 3.897 | 42.186 | 28.539 | 1.00 | 14.81 | F | O |
| ATOM | 5344 | N | ILE | F | 146 | 5.389 | 43.384 | 29.720 | 1.00 | 15.25 | F | N |
| ATOM | 5345 | CA | ILE | F | 146 | 5.341 | 42.482 | 30.864 | 1.00 | 15.07 | F | C |
| ATOM | 5346 | CB | ILE | F | 146 | 6.368 | 42.909 | 31.941 | 1.00 | 16.98 | F | C |
| ATOM | 5347 | CG2 | ILE | F | 146 | 6.004 | 42.322 | 33.305 | 1.00 | 13.25 | F | C |
| ATOM | 5348 | CG1 | ILE | F | 146 | 7.764 | 42.452 | 31.523 | 1.00 | 13.05 | F | C |
| ATOM | 5349 | CD1 | ILE | F | 146 | 8.864 | 43.188 | 32.247 | 1.00 | 13.47 | F | C |
| ATOM | 5350 | C | ILE | F | 146 | 3.932 | 42.451 | 31.466 | 1.00 | 15.79 | F | C |
| ATOM | 5351 | O | ILE | F | 146 | 3.388 | 41.372 | 31.731 | 1.00 | 16.53 | F | O |
| ATOM | 5352 | N | ARG | F | 147 | 3.336 | 43.626 | 31.673 | 1.00 | 13.60 | F | N |
| ATOM | 5353 | CA | ARG | F | 147 | 1.994 | 43.674 | 32.247 | 1.00 | 15.57 | F | C |
| ATOM | 5354 | CB | ARG | F | 147 | 1.560 | 45.114 | 32.542 | 1.00 | 11.32 | F | C |
| ATOM | 5355 | CG | ARG | F | 147 | 0.078 | 45.193 | 32.925 | 1.00 | 6.74 | F | C |
| ATOM | 5356 | CD | ARG | F | 147 | −0.273 | 46.472 | 33.645 | 1.00 | 7.75 | F | C |
| ATOM | 5357 | NE | ARG | F | 147 | −1.700 | 46.529 | 33.957 | 1.00 | 9.74 | F | N |
| ATOM | 5358 | CZ | ARG | F | 147 | −2.259 | 46.007 | 35.050 | 1.00 | 11.93 | F | C |
| ATOM | 5359 | NH1 | ARG | F | 147 | −1.502 | 45.382 | 35.947 | 1.00 | 9.63 | F | N |
| ATOM | 5360 | NH2 | ARG | F | 147 | −3.574 | 46.105 | 35.244 | 1.00 | 9.00 | F | N |
| ATOM | 5361 | C | ARG | F | 147 | 0.956 | 43.014 | 31.331 | 1.00 | 17.15 | F | C |
| ATOM | 5362 | O | ARG | F | 147 | 0.111 | 42.233 | 31.805 | 1.00 | 17.46 | F | O |
| ATOM | 5363 | N | GLU | F | 148 | 1.008 | 43.343 | 30.034 | 1.00 | 16.24 | F | N |
| ATOM | 5364 | CA | GLU | F | 148 | 0.087 | 42.768 | 29.046 | 1.00 | 14.76 | F | C |
| ATOM | 5365 | CB | GLU | F | 148 | 0.423 | 43.270 | 27.629 | 1.00 | 15.15 | F | C |
| ATOM | 5366 | CG | GLU | F | 148 | −0.480 | 42.673 | 26.539 | 1.00 | 15.57 | F | C |
| ATOM | 5367 | CD | GLU | F | 148 | 0.045 | 42.916 | 25.127 | 1.00 | 21.01 | F | C |
| ATOM | 5368 | OE1 | GLU | F | 148 | −0.709 | 43.429 | 24.272 | 1.00 | 24.02 | F | O |
| ATOM | 5369 | OE2 | GLU | F | 148 | 1.216 | 42.592 | 24.867 | 1.00 | 22.01 | F | O |
| ATOM | 5370 | C | GLU | F | 148 | 0.185 | 41.234 | 29.070 | 1.00 | 15.20 | F | C |
| ATOM | 5371 | O | GLU | F | 148 | −0.825 | 40.532 | 29.011 | 1.00 | 16.69 | F | O |
| ATOM | 5372 | N | LYS | F | 149 | 1.410 | 40.721 | 29.161 | 1.00 | 13.11 | F | N |
| ATOM | 5373 | CA | LYS | F | 149 | 1.631 | 39.282 | 29.200 | 1.00 | 13.81 | F | C |
| ATOM | 5374 | CB | LYS | F | 149 | 3.124 | 38.988 | 29.273 | 1.00 | 12.03 | F | C |
| ATOM | 5375 | CG | LYS | F | 149 | 3.444 | 37.501 | 29.322 | 1.00 | 15.18 | F | C |
| ATOM | 5376 | CD | LYS | F | 149 | 4.944 | 37.259 | 29.252 | 1.00 | 14.84 | F | C |
| ATOM | 5377 | CE | LYS | F | 149 | 5.679 | 37.873 | 30.445 | 1.00 | 17.37 | F | C |
| ATOM | 5378 | NZ | LYS | F | 149 | 7.117 | 37.455 | 30.484 | 1.00 | 13.89 | F | N |
| ATOM | 5379 | C | LYS | F | 149 | 0.938 | 38.611 | 30.386 | 1.00 | 15.87 | F | C |
| ATOM | 5380 | O | LYS | F | 149 | 0.197 | 37.635 | 30.209 | 1.00 | 15.87 | F | O |
| ATOM | 5381 | N | TYR | F | 150 | 1.172 | 39.137 | 31.590 | 1.00 | 12.07 | F | N |
| ATOM | 5382 | CA | TYR | F | 150 | 0.577 | 38.556 | 32.782 | 1.00 | 11.95 | F | C |
| ATOM | 5383 | CB | TYR | F | 150 | 1.294 | 39.102 | 34.023 | 1.00 | 14.19 | F | C |
| ATOM | 5384 | CG | TYR | F | 150 | 2.689 | 38.539 | 34.139 | 1.00 | 13.74 | F | C |
| ATOM | 5385 | CD1 | TYR | F | 150 | 2.885 | 37.181 | 34.386 | 1.00 | 17.50 | F | C |
| ATOM | 5386 | CE1 | TYR | F | 150 | 4.165 | 36.628 | 34.417 | 1.00 | 15.47 | F | C |
| ATOM | 5387 | CD2 | TYR | F | 150 | 3.815 | 39.337 | 33.931 | 1.00 | 16.72 | F | C |
| ATOM | 5388 | CE2 | TYR | F | 150 | 5.104 | 38.793 | 33.961 | 1.00 | 15.59 | F | C |
| ATOM | 5389 | CZ | TYR | F | 150 | 5.264 | 37.436 | 34.200 | 1.00 | 17.56 | F | C |
| ATOM | 5390 | OH | TYR | F | 150 | 6.517 | 36.874 | 34.194 | 1.00 | 17.90 | F | O |
| ATOM | 5391 | C | TYR | F | 150 | −0.923 | 38.754 | 32.862 | 1.00 | 10.46 | F | C |
| ATOM | 5392 | O | TYR | F | 150 | −1.634 | 37.913 | 33.406 | 1.00 | 10.64 | F | O |
| ATOM | 5393 | N | MET | F | 151 | −1.417 | 39.855 | 32.305 | 1.00 | 12.42 | F | N |
| ATOM | 5394 | CA | MET | F | 151 | −2.864 | 40.108 | 32.315 | 1.00 | 14.39 | F | C |
| ATOM | 5395 | CB | MET | F | 151 | −3.171 | 41.536 | 31.829 | 1.00 | 11.55 | F | C |
| ATOM | 5396 | CG | MET | F | 151 | −2.843 | 42.640 | 32.835 | 1.00 | 13.09 | F | C |
| ATOM | 5397 | SD | MET | F | 151 | −3.640 | 42.396 | 34.462 | 1.00 | 19.62 | F | S |
| ATOM | 5398 | CE | MET | F | 151 | −2.242 | 41.671 | 35.410 | 1.00 | 8.63 | F | C |
| ATOM | 5399 | C | MET | F | 151 | −3.580 | 39.092 | 31.407 | 1.00 | 17.69 | F | C |
| ATOM | 5400 | O | MET | F | 151 | −4.482 | 38.367 | 31.846 | 1.00 | 18.11 | F | O |
| ATOM | 5401 | N | LEU | F | 152 | −3.163 | 39.036 | 30.141 | 1.00 | 18.58 | F | N |
| ATOM | 5402 | CA | LEU | F | 152 | −3.760 | 38.124 | 29.170 | 1.00 | 17.83 | F | C |
| ATOM | 5403 | CB | LEU | F | 152 | −3.048 | 38.268 | 27.820 | 1.00 | 21.82 | F | C |
| ATOM | 5404 | CG | LEU | F | 152 | −3.123 | 39.639 | 27.130 | 1.00 | 26.58 | F | C |
| ATOM | 5405 | CD1 | LEU | F | 152 | −2.822 | 39.462 | 25.643 | 1.00 | 25.89 | F | C |
| ATOM | 5406 | CD2 | LEU | F | 152 | −4.508 | 40.271 | 27.322 | 1.00 | 28.33 | F | C |
| ATOM | 5407 | C | LEU | F | 152 | −3.714 | 36.666 | 29.608 | 1.00 | 16.23 | F | C |
| ATOM | 5408 | O | LEU | F | 152 | −4.701 | 35.934 | 29.493 | 1.00 | 17.14 | F | O |
| ATOM | 5409 | N | LYS | F | 153 | −2.564 | 36.240 | 30.111 | 1.00 | 15.73 | F | N |
| ATOM | 5410 | CA | LYS | F | 153 | −2.397 | 34.864 | 30.540 | 1.00 | 17.51 | F | C |
| ATOM | 5411 | CB | LYS | F | 153 | −0.900 | 34.587 | 30.728 | 1.00 | 19.95 | F | C |
| ATOM | 5412 | CG | LYS | F | 153 | −0.488 | 33.984 | 32.047 | 1.00 | 27.18 | F | C |
| ATOM | 5413 | CD | LYS | F | 153 | 0.962 | 34.327 | 32.382 | 1.00 | 30.13 | F | C |
| ATOM | 5414 | CE | LYS | F | 153 | 1.863 | 34.168 | 31.175 | 1.00 | 33.03 | F | C |
| ATOM | 5415 | NZ | LYS | F | 153 | 3.302 | 34.135 | 31.567 | 1.00 | 38.90 | F | N |
| ATOM | 5416 | C | LYS | F | 153 | −3.215 | 34.477 | 31.781 | 1.00 | 18.69 | F | C |
| ATOM | 5417 | O | LYS | F | 153 | −3.376 | 33.288 | 32.070 | 1.00 | 19.52 | F | O |
| ATOM | 5418 | N | SER | F | 154 | −3.751 | 35.468 | 32.496 | 1.00 | 17.06 | F | N |
| ATOM | 5419 | CA | SER | F | 154 | −4.561 | 35.191 | 33.683 | 1.00 | 17.60 | F | C |
| ATOM | 5420 | CB | SER | F | 154 | −3.987 | 35.899 | 34.923 | 1.00 | 17.65 | F | C |
| ATOM | 5421 | OG | SER | F | 154 | −3.984 | 37.316 | 34.787 | 1.00 | 19.27 | F | O |
| ATOM | 5422 | C | SER | F | 154 | −6.006 | 35.613 | 33.466 | 1.00 | 18.27 | F | C |
| ATOM | 5423 | O | SER | F | 154 | −6.812 | 35.599 | 34.396 | 1.00 | 19.42 | F | O |
| ATOM | 5424 | N | PHE | F | 155 | −6.329 | 35.987 | 32.231 | 1.00 | 17.51 | F | N |
| ATOM | 5425 | CA | PHE | F | 155 | −7.684 | 36.404 | 31.872 | 1.00 | 16.50 | F | C |
| ATOM | 5426 | CB | PHE | F | 155 | −8.676 | 35.275 | 32.161 | 1.00 | 20.03 | F | C |
| ATOM | 5427 | CG | PHE | F | 155 | −8.446 | 34.056 | 31.326 | 1.00 | 21.80 | F | C |
| ATOM | 5428 | CD1 | PHE | F | 155 | −9.145 | 33.870 | 30.140 | 1.00 | 22.70 | F | C |
| ATOM | 5429 | CD2 | PHE | F | 155 | −7.474 | 33.122 | 31.690 | 1.00 | 23.44 | F | C |
| ATOM | 5430 | CE1 | PHE | F | 155 | −8.870 | 32.764 | 29.321 | 1.00 | 24.21 | F | C |
| ATOM | 5431 | CE2 | PHE | F | 155 | −7.190 | 32.014 | 30.877 | 1.00 | 21.51 | F | C |
| ATOM | 5432 | CZ | PHE | F | 155 | −7.888 | 31.839 | 29.692 | 1.00 | 23.28 | F | C |
| ATOM | 5433 | C | PHE | F | 155 | −8.139 | 37.680 | 32.560 | 1.00 | 15.17 | F | C |
| ATOM | 5434 | O | PHE | F | 155 | −9.322 | 37.850 | 32.882 | 1.00 | 13.47 | F | O |
| ATOM | 5435 | N | GLN | F | 156 | −7.190 | 38.575 | 32.786 | 1.00 | 11.28 | F | N |
| ATOM | 5436 | CA | GLN | F | 156 | −7.493 | 39.844 | 33.404 | 1.00 | 10.62 | F | C |
| ATOM | 5437 | CB | GLN | F | 156 | −6.509 | 40.101 | 34.530 | 1.00 | 10.41 | F | C |
| ATOM | 5438 | CG | GLN | F | 156 | −6.687 | 39.116 | 35.689 | 1.00 | 10.31 | F | C |
| ATOM | 5439 | CD | GLN | F | 156 | −6.008 | 39.598 | 36.944 | 1.00 | 10.74 | F | C |
| ATOM | 5440 | OE1 | GLN | F | 156 | −4.807 | 39.386 | 37.135 | 1.00 | 13.18 | F | O |
| ATOM | 5441 | NE2 | GLN | F | 156 | −6.764 | 40.272 | 37.804 | 1.00 | 7.92 | F | N |
| ATOM | 5442 | C | GLN | F | 156 | −7.393 | 40.888 | 32.294 | 1.00 | 14.28 | F | C |
| ATOM | 5443 | O | GLN | F | 156 | −6.868 | 40.597 | 31.224 | 1.00 | 16.37 | F | O |
| ATOM | 5444 | N | ARG | F | 157 | −7.877 | 42.100 | 32.536 | 1.00 | 15.44 | F | N |
| ATOM | 5445 | CA | ARG | F | 157 | −7.885 | 43.129 | 31.499 | 1.00 | 14.57 | F | C |
| ATOM | 5446 | CB | ARG | F | 157 | −9.093 | 44.036 | 31.728 | 1.00 | 12.85 | F | C |
| ATOM | 5447 | CG | ARG | F | 157 | −10.382 | 43.245 | 31.938 | 1.00 | 15.10 | F | C |
| ATOM | 5448 | CD | ARG | F | 157 | −11.543 | 44.105 | 32.449 | 1.00 | 12.60 | F | C |
| ATOM | 5449 | NE | ARG | F | 157 | −11.320 | 44.577 | 33.809 | 1.00 | 11.23 | F | N |
| ATOM | 5450 | CZ | ARG | F | 157 | −12.198 | 45.284 | 34.510 | 1.00 | 11.19 | F | C |
| ATOM | 5451 | NH1 | ARG | F | 157 | −11.911 | 45.673 | 35.739 | 1.00 | 11.39 | F | N |
| ATOM | 5452 | NH2 | ARG | F | 157 | −13.367 | 45.605 | 33.991 | 1.00 | 13.34 | F | N |
| ATOM | 5453 | C | ARG | F | 157 | −6.651 | 43.989 | 31.277 | 1.00 | 15.38 | F | C |
| ATOM | 5454 | O | ARG | F | 157 | −5.923 | 44.331 | 32.215 | 1.00 | 16.76 | F | O |
| ATOM | 5455 | N | PHE | F | 158 | −6.416 | 44.307 | 30.005 | 1.00 | 15.79 | F | N |
| ATOM | 5456 | CA | PHE | F | 158 | −5.323 | 45.188 | 29.561 | 1.00 | 13.85 | F | C |
| ATOM | 5457 | CB | PHE | F | 158 | −4.089 | 44.388 | 29.144 | 1.00 | 11.34 | F | C |
| ATOM | 5458 | CG | PHE | F | 158 | −2.883 | 45.247 | 28.878 | 1.00 | 13.88 | F | C |
| ATOM | 5459 | CD1 | PHE | F | 158 | −2.527 | 45.600 | 27.572 | 1.00 | 10.07 | F | C |
| ATOM | 5460 | CD2 | PHE | F | 158 | −2.135 | 45.749 | 29.924 | 1.00 | 12.69 | F | C |
| ATOM | 5461 | CE1 | PHE | F | 158 | −1.450 | 46.443 | 27.313 | 1.00 | 9.58 | F | C |
| ATOM | 5462 | CE2 | PHE | F | 158 | −1.046 | 46.601 | 29.678 | 1.00 | 15.73 | F | C |
| ATOM | 5463 | CZ | PHE | F | 158 | −0.704 | 46.949 | 28.361 | 1.00 | 13.17 | F | C |
| ATOM | 5464 | C | PHE | F | 158 | −5.942 | 45.943 | 28.363 | 1.00 | 15.19 | F | C |
| ATOM | 5465 | O | PHE | F | 158 | −6.478 | 45.319 | 27.452 | 1.00 | 14.12 | F | O |
| ATOM | 5466 | N | PRO | F | 159 | −5.891 | 47.292 | 28.365 | 1.00 | 15.48 | F | N |
| ATOM | 5467 | CD | PRO | F | 159 | −5.233 | 48.139 | 29.379 | 1.00 | 14.75 | F | C |
| ATOM | 5468 | CA | PRO | F | 159 | −6.472 | 48.097 | 27.278 | 1.00 | 15.30 | F | C |
| ATOM | 5469 | CB | PRO | F | 159 | −6.350 | 49.535 | 27.789 | 1.00 | 13.46 | F | C |
| ATOM | 5470 | CG | PRO | F | 159 | −5.179 | 49.492 | 28.716 | 1.00 | 16.64 | F | C |
| ATOM | 5471 | C | PRO | F | 159 | −5.865 | 47.910 | 25.879 | 1.00 | 15.75 | F | C |
| ATOM | 5472 | O | PRO | F | 159 | −4.666 | 47.662 | 25.716 | 1.00 | 14.53 | F | O |
| ATOM | 5473 | N | LYS | F | 160 | −6.724 | 48.038 | 24.874 | 1.00 | 16.54 | F | N |
| ATOM | 5474 | CA | LYS | F | 160 | −6.345 | 47.865 | 23.478 | 1.00 | 17.18 | F | C |
| ATOM | 5475 | CB | LYS | F | 160 | −7.596 | 47.860 | 22.595 | 1.00 | 19.00 | F | C |
| ATOM | 5476 | CG | LYS | F | 160 | −8.443 | 46.615 | 22.762 | 1.00 | 24.89 | F | C |
| ATOM | 5477 | CD | LYS | F | 160 | −9.775 | 46.728 | 22.017 | 1.00 | 33.23 | F | C |
| ATOM | 5478 | CE | LYS | F | 160 | −10.589 | 47.944 | 22.482 | 1.00 | 37.71 | F | C |
| ATOM | 5479 | NZ | LYS | F | 160 | −11.518 | 47.633 | 23.609 | 1.00 | 37.86 | F | N |
| ATOM | 5480 | C | LYS | F | 160 | −5.372 | 48.898 | 22.936 | 1.00 | 16.14 | F | C |
| ATOM | 5481 | O | LYS | F | 160 | −4.364 | 48.536 | 22.319 | 1.00 | 15.10 | F | O |
| ATOM | 5482 | N | THR | F | 161 | −5.632 | 50.181 | 23.169 | 1.00 | 14.47 | F | N |
| ATOM | 5483 | CA | THR | F | 161 | −4.733 | 51.148 | 22.581 | 1.00 | 16.63 | F | C |
| ATOM | 5484 | CB | THR | F | 161 | −5.195 | 52.601 | 22.811 | 1.00 | 15.74 | F | C |
| ATOM | 5485 | OG1 | THR | F | 161 | −4.413 | 53.217 | 23.821 | 1.00 | 28.67 | F | O |
| ATOM | 5486 | CG2 | THR | F | 161 | −6.634 | 52.640 | 23.155 | 1.00 | 14.49 | F | C |
| ATOM | 5487 | C | THR | F | 161 | −3.269 | 50.924 | 22.912 | 1.00 | 18.88 | F | C |
| ATOM | 5488 | O | THR | F | 161 | −2.427 | 51.001 | 22.014 | 1.00 | 21.25 | F | O |
| ATOM | 5489 | N | PRO | F | 162 | −2.922 | 50.642 | 24.185 | 1.00 | 19.86 | F | N |
| ATOM | 5490 | CD | PRO | F | 162 | −3.702 | 50.561 | 25.432 | 1.00 | 20.85 | F | C |
| ATOM | 5491 | CA | PRO | F | 162 | −1.487 | 50.418 | 24.419 | 1.00 | 17.90 | F | C |
| ATOM | 5492 | CB | PRO | F | 162 | −1.377 | 50.220 | 25.935 | 1.00 | 16.75 | F | C |
| ATOM | 5493 | CG | PRO | F | 162 | −2.656 | 50.719 | 26.497 | 1.00 | 17.13 | F | C |
| ATOM | 5494 | C | PRO | F | 162 | −0.994 | 49.177 | 23.653 | 1.00 | 15.49 | F | C |
| ATOM | 5495 | O | PRO | F | 162 | 0.135 | 49.150 | 23.195 | 1.00 | 16.56 | F | O |
| ATOM | 5496 | N | SER | F | 163 | −1.835 | 48.149 | 23.534 | 1.00 | 15.26 | F | N |
| ATOM | 5497 | CA | SER | F | 163 | −1.461 | 46.923 | 22.813 | 1.00 | 16.81 | F | C |
| ATOM | 5498 | CB | SER | F | 163 | −2.579 | 45.892 | 22.895 | 1.00 | 17.53 | F | C |
| ATOM | 5499 | OG | SER | F | 163 | −2.530 | 45.196 | 24.128 | 1.00 | 24.52 | F | O |
| ATOM | 5500 | C | SER | F | 163 | −1.185 | 47.242 | 21.342 | 1.00 | 18.26 | F | C |
| ATOM | 5501 | O | SER | F | 163 | −0.190 | 46.789 | 20.773 | 1.00 | 17.07 | F | O |
| ATOM | 5502 | N | LYS | F | 164 | −2.064 | 48.035 | 20.736 | 1.00 | 18.75 | F | N |
| ATOM | 5503 | CA | LYS | F | 164 | −1.890 | 48.431 | 19.343 | 1.00 | 20.59 | F | C |
| ATOM | 5504 | CB | LYS | F | 164 | −2.963 | 49.439 | 18.938 | 1.00 | 16.84 | F | C |
| ATOM | 5505 | CG | LYS | F | 164 | −4.315 | 48.798 | 18.721 | 1.00 | 17.99 | F | C |
| ATOM | 5506 | CD | LYS | F | 164 | −5.383 | 49.844 | 18.540 | 1.00 | 20.31 | F | C |
| ATOM | 5507 | CE | LYS | F | 164 | −6.721 | 49.177 | 18.331 | 1.00 | 25.84 | F | C |
| ATOM | 5508 | NZ | LYS | F | 164 | −7.778 | 50.188 | 18.053 | 1.00 | 31.32 | F | N |
| ATOM | 5509 | C | LYS | F | 164 | −0.504 | 49.039 | 19.160 | 1.00 | 21.99 | F | C |
| ATOM | 5510 | O | LYS | F | 164 | 0.210 | 48.703 | 18.212 | 1.00 | 23.96 | F | O |
| ATOM | 5511 | N | TYR | F | 165 | −0.112 | 49.932 | 20.064 | 1.00 | 21.05 | F | N |
| ATOM | 5512 | CA | TYR | F | 165 | 1.211 | 50.534 | 19.964 | 1.00 | 20.44 | F | C |
| ATOM | 5513 | CB | TYR | F | 165 | 1.373 | 51.653 | 20.997 | 1.00 | 18.45 | F | C |
| ATOM | 5514 | CG | TYR | F | 165 | 0.886 | 52.995 | 20.501 | 1.00 | 18.86 | F | C |
| ATOM | 5515 | CD1 | TYR | F | 165 | 1.670 | 53.765 | 19.651 | 1.00 | 15.67 | F | C |
| ATOM | 5516 | CE1 | TYR | F | 165 | 1.211 | 54.990 | 19.154 | 1.00 | 16.76 | F | C |
| ATOM | 5517 | CD2 | TYR | F | 165 | −0.378 | 53.480 | 20.856 | 1.00 | 19.26 | F | C |
| ATOM | 5518 | CE2 | TYR | F | 165 | −0.850 | 54.712 | 20.364 | 1.00 | 19.33 | F | C |
| ATOM | 5519 | CZ | TYR | F | 165 | −0.041 | 55.452 | 19.509 | 1.00 | 18.66 | F | C |
| ATOM | 5520 | OH | TYR | F | 165 | −0.489 | 56.632 | 18.961 | 1.00 | 24.89 | F | O |
| ATOM | 5521 | C | TYR | F | 165 | 2.327 | 49.493 | 20.150 | 1.00 | 21.70 | F | C |
| ATOM | 5522 | O | TYR | F | 165 | 3.384 | 49.591 | 19.524 | 1.00 | 24.23 | F | O |
| ATOM | 5523 | N | LEU | F | 166 | 2.103 | 48.502 | 21.010 | 1.00 | 21.48 | F | N |
| ATOM | 5524 | CA | LEU | F | 166 | 3.117 | 47.478 | 21.253 | 1.00 | 22.03 | F | C |
| ATOM | 5525 | CB | LEU | F | 166 | 2.685 | 46.552 | 22.417 | 1.00 | 22.81 | F | C |
| ATOM | 5526 | CG | LEU | F | 166 | 2.609 | 47.154 | 23.844 | 1.00 | 23.53 | F | C |
| ATOM | 5527 | CD1 | LEU | F | 166 | 2.047 | 46.128 | 24.806 | 1.00 | 20.37 | F | C |
| ATOM | 5528 | CD2 | LEU | F | 166 | 3.992 | 47.614 | 24.319 | 1.00 | 17.34 | F | C |
| ATOM | 5529 | C | LEU | F | 166 | 3.320 | 46.668 | 19.970 | 1.00 | 21.07 | F | C |
| ATOM | 5530 | O | LEU | F | 166 | 4.448 | 46.388 | 19.559 | 1.00 | 21.15 | F | O |
| ATOM | 5531 | N | ARG | F | 167 | 2.214 | 46.295 | 19.339 | 1.00 | 19.56 | F | N |
| ATOM | 5532 | CA | ARG | F | 167 | 2.273 | 45.527 | 18.103 | 1.00 | 21.20 | F | C |
| ATOM | 5533 | CB | ARG | F | 167 | 0.857 | 45.192 | 17.625 | 1.00 | 17.15 | F | C |
| ATOM | 5534 | CG | ARG | F | 167 | 0.084 | 44.214 | 18.533 | 1.00 | 21.82 | F | C |
| ATOM | 5535 | CD | ARG | F | 167 | 0.835 | 42.894 | 18.822 | 1.00 | 20.10 | F | C |
| ATOM | 5536 | NE | ARG | F | 167 | 1.787 | 42.999 | 19.940 | 1.00 | 22.65 | F | N |
| ATOM | 5537 | CZ | ARG | F | 167 | 1.459 | 43.041 | 21.239 | 1.00 | 19.33 | F | C |
| ATOM | 5538 | NH1 | ARG | F | 167 | 0.193 | 42.985 | 21.627 | 1.00 | 16.84 | F | N |
| ATOM | 5539 | NH2 | ARG | F | 167 | 2.407 | 43.166 | 22.159 | 1.00 | 15.73 | F | N |
| ATOM | 5540 | C | ARG | F | 167 | 3.039 | 46.325 | 17.036 | 1.00 | 22.33 | F | C |
| ATOM | 5541 | O | ARG | F | 167 | 3.939 | 45.787 | 16.395 | 1.00 | 22.03 | F | O |
| ATOM | 5542 | N | SER | F | 168 | 2.694 | 47.607 | 16.872 | 1.00 | 24.54 | F | N |
| ATOM | 5543 | CA | SER | F | 168 | 3.351 | 48.486 | 15.896 | 1.00 | 24.93 | F | C |
| ATOM | 5544 | CB | SER | F | 168 | 2.821 | 49.903 | 15.989 | 1.00 | 25.65 | F | C |
| ATOM | 5545 | OG | SER | F | 168 | 1.464 | 49.943 | 15.608 | 1.00 | 39.32 | F | O |
| ATOM | 5546 | C | SER | F | 168 | 4.830 | 48.555 | 16.153 | 1.00 | 26.66 | F | C |
| ATOM | 5547 | O | SER | F | 168 | 5.644 | 48.453 | 15.237 | 1.00 | 27.96 | F | O |
| ATOM | 5548 | N | ILE | F | 169 | 5.182 | 48.771 | 17.409 | 1.00 | 24.77 | F | N |
| ATOM | 5549 | CA | ILE | F | 169 | 6.578 | 48.851 | 17.764 | 1.00 | 26.00 | F | C |
| ATOM | 5550 | CB | ILE | F | 169 | 6.734 | 49.129 | 19.270 | 1.00 | 27.33 | F | C |
| ATOM | 5551 | CG2 | ILE | F | 169 | 8.129 | 48.717 | 19.745 | 1.00 | 24.04 | F | C |
| ATOM | 5552 | CG1 | ILE | F | 169 | 6.453 | 50.612 | 19.535 | 1.00 | 25.37 | F | C |
| ATOM | 5553 | CD1 | ILE | F | 169 | 6.331 | 50.954 | 20.982 | 1.00 | 24.97 | F | C |
| ATOM | 5554 | C | ILE | F | 169 | 7.276 | 47.550 | 17.400 | 1.00 | 26.53 | F | C |
| ATOM | 5555 | O | ILE | F | 169 | 8.435 | 47.556 | 17.005 | 1.00 | 26.07 | F | O |
| ATOM | 5556 | N | GLU | F | 170 | 6.562 | 46.437 | 17.531 | 1.00 | 29.35 | F | N |
| ATOM | 5557 | CA | GLU | F | 170 | 7.124 | 45.127 | 17.218 | 1.00 | 34.11 | F | C |
| ATOM | 5558 | CB | GLU | F | 170 | 6.284 | 44.022 | 17.862 | 1.00 | 32.28 | F | C |
| ATOM | 5559 | CG | GLU | F | 170 | 6.528 | 43.867 | 19.337 | 1.00 | 35.23 | F | C |
| ATOM | 5560 | CD | GLU | F | 170 | 5.322 | 43.306 | 20.062 | 1.00 | 37.29 | F | C |
| ATOM | 5561 | OE1 | GLU | F | 170 | 5.187 | 43.553 | 21.285 | 1.00 | 35.24 | F | O |
| ATOM | 5562 | OE2 | GLU | F | 170 | 4.510 | 42.620 | 19.399 | 1.00 | 37.58 | F | O |
| ATOM | 5563 | C | GLU | F | 170 | 7.216 | 44.866 | 15.714 | 1.00 | 36.62 | F | C |
| ATOM | 5564 | O | GLU | F | 170 | 8.019 | 44.046 | 15.275 | 1.00 | 37.88 | F | O |
| ATOM | 5565 | N | GLY | F | 171 | 6.391 | 45.555 | 14.932 | 1.00 | 38.64 | F | N |
| ATOM | 5566 | CA | GLY | F | 171 | 6.407 | 45.355 | 13.497 | 1.00 | 40.10 | F | C |
| ATOM | 5567 | C | GLY | F | 171 | 5.326 | 44.390 | 13.045 | 1.00 | 42.38 | F | C |
| ATOM | 5568 | O | GLY | F | 171 | 5.348 | 43.911 | 11.911 | 1.00 | 45.43 | F | O |
| ATOM | 5569 | N | THR | F | 172 | 4.378 | 44.096 | 13.927 | 1.00 | 43.11 | F | N |
| ATOM | 5570 | CA | THR | F | 172 | 3.300 | 43.187 | 13.583 | 1.00 | 44.39 | F | C |
| ATOM | 5571 | CB | THR | F | 172 | 3.223 | 42.033 | 14.593 | 1.00 | 43.98 | F | C |
| ATOM | 5572 | OG1 | THR | F | 172 | 2.400 | 42.416 | 15.697 | 1.00 | 50.06 | F | O |
| ATOM | 5573 | CG2 | THR | F | 172 | 4.602 | 41.702 | 15.117 | 1.00 | 42.72 | F | C |
| ATOM | 5574 | C | THR | F | 172 | 1.973 | 43.945 | 13.525 | 1.00 | 46.14 | F | C |
| ATOM | 5575 | O | THR | F | 172 | 1.881 | 45.093 | 13.965 | 1.00 | 44.19 | F | O |
| ATOM | 5576 | N | ALA | F | 173 | 0.954 | 43.311 | 12.951 | 1.00 | 49.36 | F | N |
| ATOM | 5577 | CA | ALA | F | 173 | −0.368 | 43.928 | 12.818 | 1.00 | 50.54 | F | C |
| ATOM | 5578 | CB | ALA | F | 173 | −1.060 | 43.444 | 11.540 | 1.00 | 51.18 | F | C |
| ATOM | 5579 | C | ALA | F | 173 | −1.209 | 43.583 | 14.032 | 1.00 | 50.20 | F | C |
| ATOM | 5580 | O | ALA | F | 173 | −1.126 | 42.472 | 14.567 | 1.00 | 51.57 | F | O |
| ATOM | 5581 | N | TRP | F | 174 | −2.027 | 44.534 | 14.463 | 1.00 | 50.32 | F | N |
| ATOM | 5582 | CA | TRP | F | 174 | −2.852 | 44.324 | 15.639 | 1.00 | 48.79 | F | C |
| ATOM | 5583 | CB | TRP | F | 174 | −3.289 | 45.665 | 16.225 | 1.00 | 47.34 | F | C |
| ATOM | 5584 | CG | TRP | F | 174 | −4.060 | 45.491 | 17.488 | 1.00 | 45.48 | F | C |
| ATOM | 5585 | CD2 | TRP | F | 174 | −5.470 | 45.643 | 17.646 | 1.00 | 45.14 | F | C |
| ATOM | 5586 | CE2 | TRP | F | 174 | −5.776 | 45.321 | 18.989 | 1.00 | 41.99 | F | C |
| ATOM | 5587 | CE3 | TRP | F | 174 | −6.509 | 46.022 | 16.783 | 1.00 | 47.03 | F | C |
| ATOM | 5588 | CD1 | TRP | F | 174 | −3.574 | 45.095 | 18.706 | 1.00 | 42.12 | F | C |
| ATOM | 5589 | NE1 | TRP | F | 174 | −4.600 | 44.990 | 19.610 | 1.00 | 39.76 | F | N |
| ATOM | 5590 | CZ2 | TRP | F | 174 | −7.083 | 45.364 | 19.492 | 1.00 | 44.54 | F | C |
| ATOM | 5591 | CZ3 | TRP | F | 174 | −7.813 | 46.066 | 17.282 | 1.00 | 47.02 | F | C |
| ATOM | 5592 | CH2 | TRP | F | 174 | −8.086 | 45.738 | 18.628 | 1.00 | 46.15 | F | C |
| ATOM | 5593 | C | TRP | F | 174 | −4.070 | 43.441 | 15.427 | 1.00 | 48.66 | F | C |
| ATOM | 5594 | O | TRP | F | 174 | −4.903 | 43.697 | 14.565 | 1.00 | 49.03 | F | O |
| ATOM | 5595 | N | LYS | F | 175 | −4.160 | 42.410 | 16.258 | 1.00 | 50.58 | F | N |
| ATOM | 5596 | CA | LYS | F | 175 | −5.248 | 41.441 | 16.234 | 1.00 | 53.41 | F | C |
| ATOM | 5597 | CB | LYS | F | 175 | −4.836 | 40.200 | 17.022 | 1.00 | 54.42 | F | C |
| ATOM | 5598 | CG | LYS | F | 175 | −3.591 | 40.408 | 17.864 | 1.00 | 55.26 | F | C |
| ATOM | 5599 | CD | LYS | F | 175 | −2.851 | 39.089 | 18.059 | 1.00 | 58.53 | F | C |
| ATOM | 5600 | CE | LYS | F | 175 | −2.472 | 38.449 | 16.720 | 1.00 | 59.04 | F | C |
| ATOM | 5601 | NZ | LYS | F | 175 | −3.519 | 37.504 | 16.200 | 1.00 | 57.96 | F | N |
| ATOM | 5602 | C | LYS | F | 175 | −6.559 | 41.963 | 16.816 | 1.00 | 54.45 | F | C |
| ATOM | 5603 | O | LYS | F | 175 | −7.054 | 43.028 | 16.437 | 1.00 | 56.86 | F | O |
| ATOM | 5604 | N | ALA | F | 176 | −7.114 | 41.184 | 17.739 | 1.00 | 54.17 | F | N |
| ATOM | 5605 | CA | ALA | F | 176 | −8.366 | 41.512 | 18.404 | 1.00 | 53.76 | F | C |
| ATOM | 5606 | CB | ALA | F | 176 | −9.445 | 41.855 | 17.369 | 1.00 | 49.41 | F | C |
| ATOM | 5607 | C | ALA | F | 176 | −8.779 | 40.286 | 19.215 | 1.00 | 55.40 | F | C |
| ATOM | 5608 | O | ALA | F | 176 | −9.886 | 40.233 | 19.756 | 1.00 | 58.76 | F | O |
| ATOM | 5609 | N | ASN | F | 177 | −7.880 | 39.305 | 19.299 | 1.00 | 55.53 | F | N |
| ATOM | 5610 | CA | ASN | F | 177 | −8.139 | 38.058 | 20.030 | 1.00 | 55.80 | F | C |
| ATOM | 5611 | CB | ASN | F | 177 | −6.814 | 37.350 | 20.348 | 1.00 | 57.18 | F | C |
| ATOM | 5612 | CG | ASN | F | 177 | −5.913 | 38.177 | 21.265 | 1.00 | 60.85 | F | C |
| ATOM | 5613 | OD1 | ASN | F | 177 | −5.497 | 39.288 | 20.916 | 1.00 | 63.93 | F | O |
| ATOM | 5614 | ND2 | ASN | F | 177 | −5.610 | 37.637 | 22.443 | 1.00 | 59.78 | F | N |
| ATOM | 5615 | C | ASN | F | 177 | −8.936 | 38.258 | 21.324 | 1.00 | 54.32 | F | C |
| ATOM | 5616 | O | ASN | F | 177 | −8.455 | 38.894 | 22.265 | 1.00 | 54.01 | F | O |
| ATOM | 5617 | N | GLU | F | 178 | −10.148 | 37.703 | 21.359 | 1.00 | 52.82 | F | N |
| ATOM | 5618 | CA | GLU | F | 178 | −11.027 | 37.812 | 22.520 | 1.00 | 50.57 | F | C |
| ATOM | 5619 | CB | GLU | F | 178 | −12.474 | 38.033 | 22.062 | 1.00 | 51.12 | F | C |
| ATOM | 5620 | CG | GLU | F | 178 | −12.767 | 39.440 | 21.571 | 1.00 | 54.04 | F | C |
| ATOM | 5621 | CD | GLU | F | 178 | −12.269 | 40.518 | 22.533 | 1.00 | 58.47 | F | C |
| ATOM | 5622 | OE1 | GLU | F | 178 | −11.117 | 40.415 | 23.008 | 1.00 | 60.02 | F | O |
| ATOM | 5623 | OE2 | GLU | F | 178 | −13.028 | 41.475 | 22.812 | 1.00 | 59.36 | F | O |
| ATOM | 5624 | C | GLU | F | 178 | −10.955 | 36.575 | 23.413 | 1.00 | 50.11 | F | C |
| ATOM | 5625 | O | GLU | F | 178 | −11.700 | 36.457 | 24.390 | 1.00 | 50.60 | F | O |
| ATOM | 5626 | N | SER | F | 179 | −10.050 | 35.659 | 23.079 | 1.00 | 48.31 | F | N |
| ATOM | 5627 | CA | SER | F | 179 | −9.880 | 34.423 | 23.836 | 1.00 | 45.36 | F | C |
| ATOM | 5628 | CB | SER | F | 179 | −8.875 | 33.506 | 23.126 | 1.00 | 43.42 | F | C |
| ATOM | 5629 | OG | SER | F | 179 | −7.888 | 34.256 | 22.435 | 1.00 | 45.34 | F | O |
| ATOM | 5630 | C | SER | F | 179 | −9.431 | 34.639 | 25.283 | 1.00 | 44.43 | F | C |
| ATOM | 5631 | O | SER | F | 179 | −9.893 | 33.934 | 26.182 | 1.00 | 44.23 | F | O |
| ATOM | 5632 | N | SER | F | 180 | −8.541 | 35.610 | 25.502 | 1.00 | 41.30 | F | N |
| ATOM | 5633 | CA | SER | F | 180 | −8.005 | 35.899 | 26.839 | 1.00 | 40.04 | F | C |
| ATOM | 5634 | CB | SER | F | 180 | −6.604 | 36.494 | 26.721 | 1.00 | 40.76 | F | C |
| ATOM | 5635 | OG | SER | F | 180 | −5.841 | 35.803 | 25.752 | 1.00 | 42.68 | F | O |
| ATOM | 5636 | C | SER | F | 180 | −8.857 | 36.839 | 27.678 | 1.00 | 38.87 | F | C |
| ATOM | 5637 | O | SER | F | 180 | −8.440 | 37.295 | 28.743 | 1.00 | 38.34 | F | O |
| ATOM | 5638 | N | TYR | F | 181 | −10.052 | 37.123 | 27.194 | 1.00 | 37.48 | F | N |
| ATOM | 5639 | CA | TYR | F | 181 | −10.962 | 38.017 | 27.881 | 1.00 | 36.93 | F | C |
| ATOM | 5640 | CB | TYR | F | 181 | −12.119 | 38.337 | 26.948 | 1.00 | 42.24 | F | C |
| ATOM | 5641 | CG | TYR | F | 181 | −12.219 | 39.773 | 26.544 | 1.00 | 46.93 | F | C |
| ATOM | 5642 | CD1 | TYR | F | 181 | −13.333 | 40.533 | 26.904 | 1.00 | 51.01 | F | C |
| ATOM | 5643 | CE1 | TYR | F | 181 | −13.461 | 41.862 | 26.502 | 1.00 | 55.45 | F | C |
| ATOM | 5644 | CD2 | TYR | F | 181 | −11.223 | 40.370 | 25.773 | 1.00 | 48.15 | F | C |
| ATOM | 5645 | CE2 | TYR | F | 181 | −11.332 | 41.702 | 25.359 | 1.00 | 52.37 | F | C |
| ATOM | 5646 | CZ | TYR | F | 181 | −12.457 | 42.446 | 25.726 | 1.00 | 56.70 | F | C |
| ATOM | 5647 | OH | TYR | F | 181 | −12.585 | 43.767 | 25.323 | 1.00 | 59.38 | F | O |
| ATOM | 5648 | C | TYR | F | 181 | −11.529 | 37.407 | 29.156 | 1.00 | 34.00 | F | C |
| ATOM | 5649 | O | TYR | F | 181 | −11.792 | 36.206 | 29.206 | 1.00 | 33.02 | F | O |
| ATOM | 5650 | N | PRO | F | 182 | −11.699 | 38.220 | 30.213 | 1.00 | 32.54 | F | N |
| ATOM | 5651 | CD | PRO | F | 182 | −11.333 | 39.642 | 30.338 | 1.00 | 31.47 | F | C |
| ATOM | 5652 | CA | PRO | F | 182 | −12.265 | 37.684 | 31.461 | 1.00 | 32.76 | F | C |
| ATOM | 5653 | CB | PRO | F | 182 | −12.187 | 38.863 | 32.438 | 1.00 | 32.20 | F | C |
| ATOM | 5654 | CG | PRO | F | 182 | −12.074 | 40.081 | 31.570 | 1.00 | 30.52 | F | C |
| ATOM | 5655 | C | PRO | F | 182 | −13.721 | 37.266 | 31.191 | 1.00 | 32.68 | F | C |
| ATOM | 5656 | O | PRO | F | 182 | −14.383 | 37.863 | 30.334 | 1.00 | 34.66 | F | O |
| ATOM | 5657 | N | VAL | F | 183 | −14.222 | 36.252 | 31.898 | 1.00 | 30.13 | F | N |
| ATOM | 5658 | CA | VAL | F | 183 | −15.596 | 35.800 | 31.687 | 1.00 | 25.07 | F | C |
| ATOM | 5659 | CB | VAL | F | 183 | −15.646 | 34.275 | 31.398 | 1.00 | 26.25 | F | C |
| ATOM | 5660 | CG1 | VAL | F | 183 | −17.072 | 33.828 | 31.175 | 1.00 | 25.71 | F | C |
| ATOM | 5661 | CG2 | VAL | F | 183 | −14.810 | 33.942 | 30.191 | 1.00 | 23.63 | F | C |
| ATOM | 5662 | C | VAL | F | 183 | −16.459 | 36.090 | 32.907 | 1.00 | 25.49 | F | C |
| ATOM | 5663 | O | VAL | F | 183 | −16.373 | 35.383 | 33.903 | 1.00 | 25.21 | F | O |
| ATOM | 5664 | N | PHE | F | 184 | −17.280 | 37.135 | 32.833 | 1.00 | 26.71 | F | N |
| ATOM | 5665 | CA | PHE | F | 184 | −18.170 | 37.500 | 33.934 | 1.00 | 29.50 | F | C |
| ATOM | 5666 | CB | PHE | F | 184 | −18.513 | 38.993 | 33.889 | 1.00 | 34.39 | F | C |
| ATOM | 5667 | CG | PHE | F | 184 | −17.352 | 39.890 | 34.196 | 1.00 | 42.05 | F | C |
| ATOM | 5668 | CD1 | PHE | F | 184 | −17.241 | 40.496 | 35.441 | 1.00 | 44.38 | F | C |
| ATOM | 5669 | CD2 | PHE | F | 184 | −16.348 | 40.106 | 33.248 | 1.00 | 43.27 | F | C |
| ATOM | 5670 | CE1 | PHE | F | 184 | −16.142 | 41.308 | 35.739 | 1.00 | 47.71 | F | C |
| ATOM | 5671 | CE2 | PHE | F | 184 | −15.249 | 40.913 | 33.537 | 1.00 | 43.92 | F | C |
| ATOM | 5672 | CZ | PHE | F | 184 | −15.145 | 41.514 | 34.782 | 1.00 | 44.21 | F | C |
| ATOM | 5673 | C | PHE | F | 184 | −19.442 | 36.702 | 33.760 | 1.00 | 30.48 | F | C |
| ATOM | 5674 | O | PHE | F | 184 | −19.895 | 36.508 | 32.628 | 1.00 | 31.58 | F | O |
| ATOM | 5675 | N | THR | F | 185 | −20.040 | 36.232 | 34.849 | 1.00 | 28.66 | F | N |
| ATOM | 5676 | CA | THR | F | 185 | −21.263 | 35.474 | 34.658 | 1.00 | 29.06 | F | C |
| ATOM | 5677 | CB | THR | F | 185 | −21.726 | 34.731 | 35.979 | 1.00 | 28.13 | F | C |
| ATOM | 5678 | OG1 | THR | F | 185 | −22.960 | 35.273 | 36.454 | 1.00 | 33.98 | F | O |
| ATOM | 5679 | CG2 | THR | F | 185 | −20.677 | 34.816 | 37.037 | 1.00 | 22.22 | F | C |
| ATOM | 5680 | C | THR | F | 185 | −22.348 | 36.397 | 34.072 | 1.00 | 28.27 | F | C |
| ATOM | 5681 | O | THR | F | 185 | −22.447 | 37.578 | 34.430 | 1.00 | 25.72 | F | O |
| ATOM | 5682 | N | PRO | F | 186 | −23.135 | 35.876 | 33.108 | 1.00 | 29.42 | F | N |
| ATOM | 5683 | CD | PRO | F | 186 | −23.021 | 34.507 | 32.575 | 1.00 | 26.47 | F | C |
| ATOM | 5684 | CA | PRO | F | 186 | −24.214 | 36.628 | 32.444 | 1.00 | 30.03 | F | C |
| ATOM | 5685 | CB | PRO | F | 186 | −24.811 | 35.626 | 31.450 | 1.00 | 25.11 | F | C |
| ATOM | 5686 | CG | PRO | F | 186 | −24.334 | 34.304 | 31.892 | 1.00 | 29.83 | F | C |
| ATOM | 5687 | C | PRO | F | 186 | −25.266 | 37.163 | 33.393 | 1.00 | 28.87 | F | C |
| ATOM | 5688 | O | PRO | F | 186 | −25.575 | 36.515 | 34.387 | 1.00 | 33.01 | F | O |
| ATOM | 5689 | N | ALA | F | 187 | −25.800 | 38.345 | 33.092 | 1.00 | 27.36 | F | N |
| ATOM | 5690 | CA | ALA | F | 187 | −26.839 | 38.953 | 33.912 | 1.00 | 27.86 | F | C |
| ATOM | 5691 | CB | ALA | F | 187 | −27.299 | 40.258 | 33.286 | 1.00 | 24.56 | F | C |
| ATOM | 5692 | C | ALA | F | 187 | −28.010 | 37.977 | 33.992 | 1.00 | 30.96 | F | C |
| ATOM | 5693 | O | ALA | F | 187 | −28.348 | 37.323 | 33.006 | 1.00 | 29.20 | F | O |
| ATOM | 5694 | N | LEU | F | 188 | −28.628 | 37.832 | 35.158 | 1.00 | 34.95 | F | N |
| ATOM | 5695 | CA | LEU | F | 188 | −29.746 | 36.918 | 35.186 | 1.00 | 37.91 | F | C |
| ATOM | 5696 | CB | LEU | F | 188 | −29.995 | 36.344 | 36.590 | 1.00 | 38.54 | F | C |
| ATOM | 5697 | CG | LEU | F | 188 | −29.985 | 37.152 | 37.875 | 1.00 | 40.39 | F | C |
| ATOM | 5698 | CD1 | LEU | F | 188 | −31.386 | 37.127 | 38.494 | 1.00 | 44.12 | F | C |
| ATOM | 5699 | CD2 | LEU | F | 188 | −28.993 | 36.541 | 38.837 | 1.00 | 38.07 | F | C |
| ATOM | 5700 | C | LEU | F | 188 | −30.941 | 37.696 | 34.654 | 1.00 | 39.12 | F | C |
| ATOM | 5701 | O | LEU | F | 188 | −31.001 | 38.921 | 34.787 | 1.00 | 36.28 | F | O |
| ATOM | 5702 | N | LYS | F | 189 | −31.857 | 36.987 | 34.003 | 1.00 | 39.79 | F | N |
| ATOM | 5703 | CA | LYS | F | 189 | −33.038 | 37.605 | 33.427 | 1.00 | 41.63 | F | C |
| ATOM | 5704 | CB | LYS | F | 189 | −33.827 | 36.562 | 32.638 | 1.00 | 39.87 | F | C |
| ATOM | 5705 | CG | LYS | F | 189 | −32.944 | 35.654 | 31.809 | 1.00 | 42.68 | F | C |
| ATOM | 5706 | CD | LYS | F | 189 | −32.833 | 36.150 | 30.383 | 1.00 | 46.01 | F | C |
| ATOM | 5707 | CE | LYS | F | 189 | −31.384 | 36.381 | 29.980 | 1.00 | 49.72 | F | C |
| ATOM | 5708 | NZ | LYS | F | 189 | −31.095 | 35.913 | 28.590 | 1.00 | 52.21 | F | N |
| ATOM | 5709 | C | LYS | F | 189 | −33.924 | 38.253 | 34.490 | 1.00 | 43.95 | F | C |
| ATOM | 5710 | O | LYS | F | 189 | −33.742 | 38.042 | 35.691 | 1.00 | 41.15 | F | O |
| ATOM | 5711 | N | LYS | F | 190 | −34.865 | 39.072 | 34.035 | 1.00 | 48.16 | F | N |
| ATOM | 5712 | CA | LYS | F | 190 | −35.806 | 39.747 | 34.924 | 1.00 | 50.93 | F | C |
| ATOM | 5713 | CB | LYS | F | 190 | −36.841 | 40.513 | 34.093 | 1.00 | 54.62 | F | C |
| ATOM | 5714 | CG | LYS | F | 190 | −37.752 | 41.446 | 34.883 | 1.00 | 56.68 | F | C |
| ATOM | 5715 | CD | LYS | F | 190 | −39.244 | 41.186 | 34.582 | 1.00 | 61.20 | F | C |
| ATOM | 5716 | CE | LYS | F | 190 | −39.577 | 41.212 | 33.072 | 1.00 | 61.39 | F | C |
| ATOM | 5717 | NZ | LYS | F | 190 | −40.471 | 40.084 | 32.654 | 1.00 | 60.19 | F | N |
| ATOM | 5718 | C | LYS | F | 190 | −36.492 | 38.667 | 35.754 | 1.00 | 52.09 | F | C |
| ATOM | 5719 | O | LYS | F | 190 | −37.178 | 37.789 | 35.217 | 1.00 | 53.66 | F | O |
| ATOM | 5720 | N | GLY | F | 191 | −36.293 | 38.720 | 37.063 | 1.00 | 51.78 | F | N |
| ATOM | 5721 | CA | GLY | F | 191 | −36.893 | 37.718 | 37.923 | 1.00 | 53.58 | F | C |
| ATOM | 5722 | C | GLY | F | 191 | −36.494 | 36.312 | 37.503 | 1.00 | 54.64 | F | C |
| ATOM | 5723 | O | GLY | F | 191 | −37.255 | 35.594 | 36.809 | 1.00 | 57.64 | F | O |
| ATOM | 5724 | N | GLU | F | 192 | −35.279 | 35.935 | 37.889 | 1.00 | 48.37 | F | N |
| ATOM | 5725 | CA | GLU | F | 192 | −34.757 | 34.610 | 37.599 | 1.00 | 44.78 | F | C |
| ATOM | 5726 | CB | GLU | F | 192 | −33.705 | 34.651 | 36.483 | 1.00 | 42.40 | F | C |
| ATOM | 5727 | CG | GLU | F | 192 | −33.214 | 33.278 | 36.042 | 1.00 | 40.40 | F | C |
| ATOM | 5728 | CD | GLU | F | 192 | −31.946 | 33.357 | 35.225 | 1.00 | 39.76 | F | C |
| ATOM | 5729 | OE1 | GLU | F | 192 | −31.298 | 32.310 | 35.014 | 1.00 | 39.34 | F | O |
| ATOM | 5730 | OE2 | GLU | F | 192 | −31.598 | 34.474 | 34.795 | 1.00 | 38.61 | F | O |
| ATOM | 5731 | C | GLU | F | 192 | −34.124 | 34.183 | 38.903 | 1.00 | 41.17 | F | C |
| ATOM | 5732 | O | GLU | F | 192 | −33.543 | 35.004 | 39.603 | 1.00 | 39.51 | F | O |
| ATOM | 5733 | N | ASP | F | 193 | −34.262 | 32.910 | 39.245 | 1.00 | 38.15 | F | N |
| ATOM | 5734 | CA | ASP | F | 193 | −33.686 | 32.402 | 40.470 | 1.00 | 31.46 | F | C |
| ATOM | 5735 | CB | ASP | F | 193 | −34.040 | 30.926 | 40.655 | 1.00 | 35.17 | F | C |
| ATOM | 5736 | CG | ASP | F | 193 | −33.489 | 30.369 | 41.935 | 1.00 | 36.30 | F | C |
| ATOM | 5737 | OD1 | ASP | F | 193 | −32.738 | 29.381 | 41.882 | 1.00 | 45.55 | F | O |
| ATOM | 5738 | OD2 | ASP | F | 193 | −33.794 | 30.927 | 42.999 | 1.00 | 38.94 | F | O |
| ATOM | 5739 | C | ASP | F | 193 | −32.171 | 32.575 | 40.435 | 1.00 | 28.54 | F | C |
| ATOM | 5740 | O | ASP | F | 193 | −31.479 | 31.999 | 39.594 | 1.00 | 26.28 | F | O |
| ATOM | 5741 | N | PRO | F | 194 | −31.634 | 33.378 | 41.364 | 1.00 | 26.35 | F | N |
| ATOM | 5742 | CD | PRO | F | 194 | −32.347 | 34.116 | 42.414 | 1.00 | 26.70 | F | C |
| ATOM | 5743 | CA | PRO | F | 194 | −30.191 | 33.616 | 41.421 | 1.00 | 25.17 | F | C |
| ATOM | 5744 | CB | PRO | F | 194 | −30.039 | 34.790 | 42.394 | 1.00 | 24.42 | F | C |
| ATOM | 5745 | CG | PRO | F | 194 | −31.412 | 35.236 | 42.731 | 1.00 | 25.03 | F | C |
| ATOM | 5746 | C | PRO | F | 194 | −29.412 | 32.417 | 41.888 | 1.00 | 21.84 | F | C |
| ATOM | 5747 | O | PRO | F | 194 | −28.195 | 32.403 | 41.791 | 1.00 | 22.80 | F | O |
| ATOM | 5748 | N | PHE | F | 195 | −30.107 | 31.401 | 42.379 | 1.00 | 22.57 | F | N |
| ATOM | 5749 | CA | PHE | F | 195 | −29.418 | 30.221 | 42.892 | 1.00 | 24.78 | F | C |
| ATOM | 5750 | CB | PHE | F | 195 | −29.711 | 30.089 | 44.393 | 1.00 | 24.63 | F | C |
| ATOM | 5751 | CG | PHE | F | 195 | −29.481 | 31.367 | 45.158 | 1.00 | 23.46 | F | C |
| ATOM | 5752 | CD1 | PHE | F | 195 | −28.185 | 31.762 | 45.498 | 1.00 | 20.74 | F | C |
| ATOM | 5753 | CD2 | PHE | F | 195 | −30.542 | 32.212 | 45.469 | 1.00 | 20.09 | F | C |
| ATOM | 5754 | CE1 | PHE | F | 195 | −27.959 | 32.976 | 46.126 | 1.00 | 20.05 | F | C |
| ATOM | 5755 | CE2 | PHE | F | 195 | −30.315 | 33.434 | 46.101 | 1.00 | 19.47 | F | C |
| ATOM | 5756 | CZ | PHE | F | 195 | −29.027 | 33.813 | 46.426 | 1.00 | 16.77 | F | C |
| ATOM | 5757 | C | PHE | F | 195 | −29.708 | 28.909 | 42.182 | 1.00 | 26.47 | F | C |
| ATOM | 5758 | O | PHE | F | 195 | −29.534 | 27.840 | 42.768 | 1.00 | 25.60 | F | O |
| ATOM | 5759 | N | ARG | F | 196 | −30.124 | 29.002 | 40.919 | 1.00 | 29.59 | F | N |
| ATOM | 5760 | CA | ARG | F | 196 | −30.454 | 27.833 | 40.108 | 1.00 | 30.75 | F | C |
| ATOM | 5761 | CB | ARG | F | 196 | −30.761 | 28.250 | 38.673 | 1.00 | 29.82 | F | C |
| ATOM | 5762 | CG | ARG | F | 196 | −31.975 | 29.124 | 38.567 | 1.00 | 33.62 | F | C |
| ATOM | 5763 | CD | ARG | F | 196 | −32.300 | 29.450 | 37.133 | 1.00 | 38.96 | F | C |
| ATOM | 5764 | NE | ARG | F | 196 | −32.201 | 28.284 | 36.263 | 1.00 | 40.53 | F | N |
| ATOM | 5765 | CZ | ARG | F | 196 | −32.727 | 28.223 | 35.046 | 1.00 | 42.38 | F | C |
| ATOM | 5766 | NH1 | ARG | F | 196 | −33.388 | 29.262 | 34.561 | 1.00 | 41.09 | F | N |
| ATOM | 5767 | NH2 | ARG | F | 196 | −32.590 | 27.126 | 34.315 | 1.00 | 44.27 | F | N |
| ATOM | 5768 | C | ARG | F | 196 | −29.329 | 26.829 | 40.108 | 1.00 | 30.98 | F | C |
| ATOM | 5769 | O | ARG | F | 196 | −28.158 | 27.184 | 39.994 | 1.00 | 30.42 | F | O |
| ATOM | 5770 | N | THR | F | 197 | −29.689 | 25.561 | 40.220 | 1.00 | 33.13 | F | N |
| ATOM | 5771 | CA | THR | F | 197 | −28.683 | 24.523 | 40.242 | 1.00 | 34.76 | F | C |
| ATOM | 5772 | CB | THR | F | 197 | −28.696 | 23.818 | 41.616 | 1.00 | 35.46 | F | C |
| ATOM | 5773 | OG1 | THR | F | 197 | −27.443 | 23.158 | 41.827 | 1.00 | 40.94 | F | O |
| ATOM | 5774 | CG2 | THR | F | 197 | −29.827 | 22.822 | 41.698 | 1.00 | 33.63 | F | C |
| ATOM | 5775 | C | THR | F | 197 | −28.897 | 23.516 | 39.117 | 1.00 | 35.07 | F | C |
| ATOM | 5776 | O | THR | F | 197 | −28.229 | 22.488 | 39.063 | 1.00 | 37.30 | F | O |
| ATOM | 5777 | N | ASP | F | 198 | −29.813 | 23.827 | 38.207 | 1.00 | 33.89 | F | N |
| ATOM | 5778 | CA | ASP | F | 198 | −30.120 | 22.935 | 37.094 | 1.00 | 36.02 | F | C |
| ATOM | 5779 | CB | ASP | F | 198 | −31.579 | 23.125 | 36.662 | 1.00 | 35.69 | F | C |
| ATOM | 5780 | CG | ASP | F | 198 | −31.893 | 24.559 | 36.236 | 1.00 | 40.09 | F | C |
| ATOM | 5781 | OD1 | ASP | F | 198 | −31.862 | 25.472 | 37.095 | 1.00 | 38.96 | F | O |
| ATOM | 5782 | OD2 | ASP | F | 198 | −32.187 | 24.774 | 35.039 | 1.00 | 38.66 | F | O |
| ATOM | 5783 | C | ASP | F | 198 | −29.213 | 23.077 | 35.875 | 1.00 | 36.33 | F | C |
| ATOM | 5784 | O | ASP | F | 198 | −29.290 | 22.285 | 34.938 | 1.00 | 38.84 | F | O |
| ATOM | 5785 | N | ASN | F | 199 | −28.327 | 24.059 | 35.901 | 1.00 | 36.77 | F | N |
| ATOM | 5786 | CA | ASN | F | 199 | −27.448 | 24.315 | 34.772 | 1.00 | 36.18 | F | C |
| ATOM | 5787 | CB | ASN | F | 199 | −27.677 | 25.753 | 34.325 | 1.00 | 40.54 | F | C |
| ATOM | 5788 | CG | ASN | F | 199 | −27.921 | 26.699 | 35.515 | 1.00 | 46.58 | F | C |
| ATOM | 5789 | OD1 | ASN | F | 199 | −28.575 | 27.739 | 35.375 | 1.00 | 45.47 | F | O |
| ATOM | 5790 | ND2 | ASN | F | 199 | −27.389 | 26.336 | 36.693 | 1.00 | 43.47 | F | N |
| ATOM | 5791 | C | ASN | F | 199 | −25.953 | 24.089 | 35.025 | 1.00 | 33.81 | F | C |
| ATOM | 5792 | O | ASN | F | 199 | −25.113 | 24.547 | 34.249 | 1.00 | 35.24 | F | O |
| ATOM | 5793 | N | LEU | F | 200 | −25.615 | 23.384 | 36.095 | 1.00 | 30.27 | F | N |
| ATOM | 5794 | CA | LEU | F | 200 | −24.215 | 23.137 | 36.412 | 1.00 | 28.96 | F | C |
| ATOM | 5795 | CB | LEU | F | 200 | −24.068 | 22.790 | 37.905 | 1.00 | 30.70 | F | C |
| ATOM | 5796 | CG | LEU | F | 200 | −24.537 | 23.801 | 38.961 | 1.00 | 30.37 | F | C |
| ATOM | 5797 | CD1 | LEU | F | 200 | −24.527 | 23.147 | 40.330 | 1.00 | 30.52 | F | C |
| ATOM | 5798 | CD2 | LEU | F | 200 | −23.616 | 25.013 | 38.958 | 1.00 | 29.81 | F | C |
| ATOM | 5799 | C | LEU | F | 200 | −23.609 | 22.012 | 35.560 | 1.00 | 28.76 | F | C |
| ATOM | 5800 | O | LEU | F | 200 | −24.274 | 21.026 | 35.265 | 1.00 | 27.88 | F | O |
| ATOM | 5801 | N | PRO | F | 201 | −22.336 | 22.161 | 35.149 | 1.00 | 28.37 | F | N |
| ATOM | 5802 | CD | PRO | F | 201 | −21.494 | 23.335 | 35.426 | 1.00 | 27.85 | F | C |
| ATOM | S803 | CA | PRO | F | 201 | −21.625 | 21.165 | 34.339 | 1.00 | 28.86 | F | C |
| ATOM | 5804 | CB | PRO | F | 201 | −20.262 | 21.812 | 34.085 | 1.00 | 27.73 | F | C |
| ATOM | 5805 | CG | PRO | F | 201 | −20.457 | 23.251 | 34.364 | 1.00 | 27.38 | F | C |
| ATOM | 5806 | C | PRO | F | 201 | −21.482 | 19.822 | 35.071 | 1.00 | 31.97 | F | C |
| ATOM | 5807 | O | PRO | F | 201 | −21.745 | 19.727 | 36.267 | 1.00 | 34.51 | F | O |
| ATOM | 5808 | N | GLU | F | 202 | −21.057 | 18.789 | 34.354 | 1.00 | 31.86 | F | N |
| ATOM | 5809 | CA | GLU | F | 202 | −20.880 | 17.468 | 34.943 | 1.00 | 34.74 | F | C |
| ATOM | 5810 | CB | GLU | F | 202 | −20.942 | 16.398 | 33.852 | 1.00 | 41.15 | F | C |
| ATOM | 5811 | CG | GLU | F | 202 | −21.942 | 16.692 | 32.728 | 1.00 | 52.47 | F | C |
| ATOM | 5812 | CD | GLU | F | 202 | −21.856 | 15.686 | 31.561 | 1.00 | 58.23 | F | C |
| ATOM | 5813 | OE1 | GLU | F | 202 | −20.840 | 15.720 | 30.816 | 1.00 | 59.06 | F | O |
| ATOM | 5814 | OE2 | GLU | F | 202 | −22.806 | 14.868 | 31.393 | 1.00 | 57.83 | F | O |
| ATOM | 5815 | C | GLU | F | 202 | −19.539 | 17.363 | 35.657 | 1.00 | 33.83 | F | C |
| ATOM | 5816 | O | GLU | F | 202 | −18.619 | 18.119 | 35.367 | 1.00 | 34.34 | F | O |
| ATOM | 5817 | N | ASN | F | 203 | −19.422 | 16.422 | 36.585 | 1.00 | 30.57 | F | N |
| ATOM | 5818 | CA | ASN | F | 203 | −18.167 | 16.246 | 37.303 | 1.00 | 32.93 | F | C |
| ATOM | 5819 | CB | ASN | F | 203 | −18.369 | 15.340 | 38.530 | 1.00 | 32.97 | F | C |
| ATOM | 5820 | CG | ASN | F | 203 | −19.350 | 15.924 | 39.547 | 1.00 | 31.87 | F | C |
| ATOM | 5821 | OD1 | ASN | F | 203 | −20.004 | 15.190 | 40.288 | 1.00 | 31.70 | F | O |
| ATOM | 5822 | ND2 | ASN | F | 203 | −19.453 | 17.242 | 39.584 | 1.00 | 33.98 | F | N |
| ATOM | 5823 | C | ASN | F | 203 | −17.128 | 15.634 | 36.360 | 1.00 | 31.63 | F | C |
| ATOM | 5824 | O | ASN | F | 203 | −17.483 | 14.889 | 35.455 | 1.00 | 32.94 | F | O |
| ATOM | 5825 | N | LEU | F | 204 | −15.852 | 15.954 | 36.568 | 1.00 | 31.63 | F | N |
| ATOM | 5826 | CA | LEU | F | 204 | −14.780 | 15.428 | 35.723 | 1.00 | 33.13 | F | C |
| ATOM | 5827 | CB | LEU | F | 204 | −13.973 | 16.566 | 35.093 | 1.00 | 32.36 | F | C |
| ATOM | 5828 | CG | LEU | F | 204 | −14.718 | 17.640 | 34.301 | 1.00 | 32.90 | F | C |
| ATOM | 5829 | CD1 | LEU | F | 204 | −13.778 | 18.819 | 34.090 | 1.00 | 32.07 | F | C |
| ATOM | 5830 | CD2 | LEU | F | 204 | −15.199 | 17.088 | 32.977 | 1.00 | 28.26 | F | C |
| ATOM | 5831 | C | LEU | F | 204 | −13.814 | 14.505 | 36.463 | 1.00 | 34.43 | F | C |
| ATOM | 5832 | O | LEU | F | 204 | −12.881 | 13.973 | 35.868 | 1.00 | 35.15 | F | O |
| ATOM | 5833 | N | GLY | F | 205 | −14.027 | 14.336 | 37.762 | 1.00 | 33.48 | F | N |
| ATOM | 5834 | CA | GLY | F | 205 | −13.173 | 13.463 | 38.543 | 1.00 | 31.78 | F | C |
| ATOM | 5835 | C | GLY | F | 205 | −11.673 | 13.540 | 38.323 | 1.00 | 32.52 | F | C |
| ATOM | 5836 | O | GLY | F | 205 | −11.003 | 12.508 | 38.416 | 1.00 | 33.93 | F | O |
| ATOM | 5837 | N | TYR | F | 206 | −11.133 | 14.723 | 38.032 | 1.00 | 32.26 | F | N |
| ATOM | 5838 | CA | TYR | F | 206 | −9.683 | 14.866 | 37.846 | 1.00 | 31.74 | F | C |
| ATOM | 5839 | CB | TYR | F | 206 | −9.335 | 16.200 | 37.192 | 1.00 | 35.11 | F | C |
| ATOM | 5840 | CG | TYR | F | 206 | −9.776 | 16.343 | 35.761 | 1.00 | 37.90 | F | C |
| ATOM | 5841 | CD1 | TYR | F | 206 | −9.974 | 15.223 | 34.955 | 1.00 | 39.66 | F | C |
| ATOM | 5842 | CE1 | TYR | F | 206 | −10.361 | 15.358 | 33.623 | 1.00 | 40.68 | F | C |
| ATOM | 5843 | CD2 | TYR | F | 206 | −9.976 | 17.605 | 35.202 | 1.00 | 36.89 | F | C |
| ATOM | 5844 | CE2 | TYR | F | 206 | −10.361 | 17.750 | 33.879 | 1.00 | 38.69 | F | C |
| ATOM | 5845 | CZ | TYR | F | 206 | −10.552 | 16.626 | 33.092 | 1.00 | 40.82 | F | C |
| ATOM | 5846 | OH | TYR | F | 206 | −10.924 | 16.770 | 31.772 | 1.00 | 43.75 | F | O |
| ATOM | 5847 | C | TYR | F | 206 | −9.035 | 14.849 | 39.223 | 1.00 | 31.85 | F | C |
| ATOM | 5848 | O | TYR | F | 206 | −9.716 | 15.014 | 40.232 | 1.00 | 31.04 | F | O |
| ATOM | 5849 | N | HIS | F | 207 | −7.720 | 14.668 | 39.270 | 1.00 | 32.98 | F | N |
| ATOM | 5850 | CA | HIS | F | 207 | −7.022 | 14.650 | 40.549 | 1.00 | 33.30 | F | C |
| ATOM | 5851 | CB | HIS | F | 207 | −6.034 | 13.478 | 40.609 | 1.00 | 33.80 | F | C |
| ATOM | 5852 | CG | HIS | F | 207 | −5.460 | 13.253 | 41.974 | 1.00 | 38.20 | F | C |
| ATOM | 5853 | CD2 | HIS | F | 207 | −6.053 | 12.922 | 43.148 | 1.00 | 39.05 | F | C |
| ATOM | 5854 | ND1 | HIS | F | 207 | −4.119 | 13.416 | 42.255 | 1.00 | 42.46 | F | N |
| ATOM | 5855 | CE1 | HIS | F | 207 | −3.912 | 13.198 | 43.544 | 1.00 | 40.73 | F | C |
| ATOM | 5856 | NE2 | HIS | F | 207 | −5.069 | 12.896 | 44.108 | 1.00 | 39.63 | F | N |
| ATOM | 5857 | C | HIS | F | 207 | −6.278 | 15.968 | 40.807 | 1.00 | 33.28 | F | C |
| ATOM | 5858 | O | HIS | F | 207 | −5.388 | 16.349 | 40.039 | 1.00 | 34.51 | F | O |
| ATOM | 5859 | N | LEU | F | 208 | −6.650 | 16.656 | 41.887 | 1.00 | 31.21 | F | N |
| ATOM | 5860 | CA | LEU | F | 208 | −6.027 | 17.923 | 42.266 | 1.00 | 28.77 | F | C |
| ATOM | 5861 | CB | LEU | F | 208 | −7.055 | 18.853 | 42.897 | 1.00 | 26.23 | F | C |
| ATOM | 5862 | CG | LEU | F | 208 | −8.299 | 19.110 | 42.065 | 1.00 | 25.70 | F | C |
| ATOM | 5863 | CD1 | LEU | F | 208 | −9.231 | 20.028 | 42.815 | 1.00 | 23.18 | F | C |
| ATOM | 5864 | CD2 | LEU | F | 208 | −7.886 | 19.708 | 40.726 | 1.00 | 27.90 | F | C |
| ATOM | 5865 | C | LEU | F | 208 | −4.909 | 17.684 | 43.270 | 1.00 | 30.16 | F | C |
| ATOM | 5866 | O | LEU | F | 208 | −5.019 | 16.836 | 44.143 | 1.00 | 32.28 | F | O |
| ATOM | 5867 | N | LYS | F | 209 | −3.836 | 18.448 | 43.161 | 1.00 | 31.57 | F | N |
| ATOM | 5868 | CA | LYS | F | 209 | −2.726 | 18.281 | 44.073 | 1.00 | 31.33 | F | C |
| ATOM | 5869 | CB | LYS | F | 209 | −1.917 | 17.059 | 43.658 | 1.00 | 32.77 | F | C |
| ATOM | 5870 | CG | LYS | F | 209 | −0.891 | 16.616 | 44.672 | 1.00 | 34.01 | F | C |
| ATOM | 5871 | CD | LYS | F | 209 | −0.172 | 15.380 | 44.170 | 1.00 | 36.98 | F | C |
| ATOM | 5872 | CE | LYS | F | 209 | 0.872 | 14.909 | 45.165 | 1.00 | 39.24 | F | C |
| ATOM | 5873 | NZ | LYS | F | 209 | 2.052 | 14.276 | 44.484 | 1.00 | 42.61 | F | N |
| ATOM | 5874 | C | LYS | F | 209 | −1.837 | 19.521 | 44.095 | 1.00 | 32.70 | F | C |
| ATOM | 5875 | O | LYS | F | 209 | −1.457 | 20.049 | 43.053 | 1.00 | 35.24 | F | O |
| ATOM | 5876 | N | MET | F | 210 | −1.513 | 19.982 | 45.293 | 1.00 | 31.38 | F | N |
| ATOM | 5877 | CA | MET | F | 210 | −0.671 | 21.148 | 45.454 | 1.00 | 30.96 | F | C |
| ATOM | 5878 | CB | MET | F | 210 | −0.669 | 21.563 | 46.923 | 1.00 | 31.39 | F | C |
| ATOM | 5879 | CG | MET | F | 210 | −0.374 | 23.033 | 47.159 | 1.00 | 35.99 | F | C |
| ATOM | 5880 | SD | MET | F | 210 | −1.803 | 24.115 | 47.041 | 1.00 | 32.63 | F | S |
| ATOM | 5881 | CE | MET | F | 210 | −3.130 | 22.934 | 46.871 | 1.00 | 28.60 | F | C |
| ATOM | 5882 | C | MET | F | 210 | 0.749 | 20.830 | 44.997 | 1.00 | 30.86 | F | C |
| ATOM | 5883 | O | MET | F | 210 | 1.259 | 19.741 | 45.241 | 1.00 | 32.00 | F | O |
| ATOM | 5884 | N | LYS | F | 211 | 1.381 | 21.780 | 44.324 | 1.00 | 30.62 | F | N |
| ATOM | 5885 | CA | LYS | F | 211 | 2.743 | 21.604 | 43.851 | 1.00 | 30.14 | F | C |
| ATOM | 5886 | CB | LYS | F | 211 | 2.751 | 21.156 | 42.398 | 1.00 | 34.00 | F | C |
| ATOM | 5887 | CG | LYS | F | 211 | 4.078 | 20.564 | 41.975 | 1.00 | 37.52 | F | C |
| ATOM | 5888 | CD | LYS | F | 211 | 4.462 | 21.039 | 40.596 | 1.00 | 40.55 | F | C |
| ATOM | 5889 | CE | LYS | F | 211 | 4.763 | 19.860 | 39.697 | 1.00 | 41.52 | F | C |
| ATOM | 5890 | NZ | LYS | F | 211 | 6.187 | 19.870 | 39.276 | 1.00 | 45.73 | F | N |
| ATOM | 5891 | C | LYS | F | 211 | 3.490 | 22.916 | 43.971 | 1.00 | 31.66 | F | C |
| ATOM | 5892 | O | LYS | F | 211 | 3.286 | 23.839 | 43.178 | 1.00 | 34.14 | F | O |
| ATOM | 5893 | N | ASP | F | 212 | 4.361 | 23.001 | 44.967 | 1.00 | 30.96 | F | N |
| ATOM | 5894 | CA | ASP | F | 212 | 5.118 | 24.217 | 45.196 | 1.00 | 30.94 | F | C |
| ATOM | 5895 | CB | ASP | F | 212 | 6.181 | 24.373 | 44.115 | 1.00 | 32.64 | F | C |
| ATOM | 5896 | CG | ASP | F | 212 | 7.276 | 23.327 | 44.226 | 1.00 | 35.02 | F | C |
| ATOM | 5897 | OD1 | ASP | F | 212 | 7.820 | 23.139 | 45.338 | 1.00 | 35.36 | F | O |
| ATOM | 5898 | OD2 | ASP | F | 212 | 7.590 | 22.693 | 43.196 | 1.00 | 37.81 | F | O |
| ATOM | 5899 | C | ASP | F | 212 | 4.228 | 25.467 | 45.265 | 1.00 | 29.90 | F | C |
| ATOM | 5900 | O | ASP | F | 212 | 4.525 | 26.500 | 44.656 | 1.00 | 30.34 | F | O |
| ATOM | 5901 | N | GLY | F | 213 | 3.128 | 25.351 | 46.005 | 1.00 | 27.60 | F | N |
| ATOM | 5902 | CA | GLY | F | 213 | 2.231 | 26.470 | 46.201 | 1.00 | 24.91 | F | C |
| ATOM | 5903 | C | GLY | F | 213 | 1.128 | 26.673 | 45.193 | 1.00 | 25.60 | F | C |
| ATOM | 5904 | O | GLY | F | 213 | 0.327 | 27.600 | 45.349 | 1.00 | 25.51 | F | O |
| ATOM | 5905 | N | VAL | F | 214 | 1.065 | 25.828 | 44.171 | 1.00 | 23.19 | F | N |
| ATOM | 5906 | CA | VAL | F | 214 | 0.026 | 25.984 | 43.158 | 1.00 | 24.91 | F | C |
| ATOM | 5907 | CB | VAL | F | 214 | 0.654 | 26.414 | 41.779 | 1.00 | 24.60 | F | C |
| ATOM | 5908 | CG1 | VAL | F | 214 | −0.434 | 26.637 | 40.727 | 1.00 | 20.39 | F | C |
| ATOM | 5909 | CG2 | VAL | F | 214 | 1.465 | 27.700 | 41.964 | 1.00 | 24.39 | F | C |
| ATOM | 5910 | C | VAL | F | 214 | −0.769 | 24.704 | 42.978 | 1.00 | 25.65 | F | C |
| ATOM | 5911 | O | VAL | F | 214 | −0.203 | 23.618 | 43.018 | 1.00 | 28.94 | F | O |
| ATOM | 5912 | N | VAL | F | 215 | −2.081 | 24.824 | 42.802 | 1.00 | 25.61 | F | N |
| ATOM | 5913 | CA | VAL | F | 215 | −2.913 | 23.643 | 42.583 | 1.00 | 25.44 | F | C |
| ATOM | 5914 | CB | VAL | F | 215 | −4.416 | 23.939 | 42.794 | 1.00 | 26.23 | F | C |
| ATOM | 5915 | CG1 | VAL | F | 215 | −5.240 | 22.666 | 42.537 | 1.00 | 24.24 | F | C |
| ATOM | 5916 | CG2 | VAL | F | 215 | −4.661 | 24.458 | 44.211 | 1.00 | 23.07 | F | C |
| ATOM | 5917 | C | VAL | F | 215 | −2.729 | 23.143 | 41.143 | 1.00 | 27.84 | F | C |
| ATOM | 5918 | O | VAL | F | 215 | −2.997 | 23.875 | 40.183 | 1.00 | 26.37 | F | O |
| ATOM | 5919 | N | TYR | F | 216 | −2.264 | 21.901 | 40.997 | 1.00 | 28.65 | F | N |
| ATOM | 5920 | CA | TYR | F | 216 | −2.058 | 21.297 | 39.680 | 1.00 | 27.89 | F | C |
| ATOM | 5921 | CB | TYR | F | 216 | −0.709 | 20.585 | 39.614 | 1.00 | 26.58 | F | C |
| ATOM | 5922 | CG | TYR | F | 216 | 0.406 | 21.493 | 39.174 | 1.00 | 26.10 | F | C |
| ATOM | 5923 | CD1 | TYR | F | 216 | 1.142 | 21.223 | 38.020 | 1.00 | 26.32 | F | C |
| ATOM | 5924 | CE1 | TYR | F | 216 | 2.161 | 22.079 | 37.598 | 1.00 | 23.07 | F | C |
| ATOM | 5925 | CD2 | TYR | F | 216 | 0.718 | 22.645 | 39.904 | 1.00 | 30.43 | F | C |
| ATOM | 5926 | CE2 | TYR | F | 216 | 1.734 | 23.508 | 39.491 | 1.00 | 26.40 | F | C |
| ATOM | 5927 | CZ | TYR | F | 216 | 2.448 | 23.218 | 38.339 | 1.00 | 26.06 | F | C |
| ATOM | 5928 | OH | TYR | F | 216 | 3.441 | 24.075 | 37.931 | 1.00 | 28.10 | F | O |
| ATOM | 5929 | C | TYR | F | 216 | −3.164 | 20.304 | 39.400 | 1.00 | 27.66 | F | C |
| ATOM | 5930 | O | TYR | F | 216 | −3.639 | 19.623 | 40.305 | 1.00 | 25.62 | F | O |
| ATOM | 5931 | N | ILE | F | 217 | −3.582 | 20.241 | 38.143 | 1.00 | 30.84 | F | N |
| ATOM | 5932 | CA | ILE | F | 217 | −4.644 | 19.333 | 37.737 | 1.00 | 33.48 | F | C |
| ATOM | 5933 | CB | ILE | F | 217 | −5.688 | 20.054 | 36.880 | 1.00 | 31.20 | F | C |
| ATOM | 5934 | CG2 | ILE | F | 217 | −6.880 | 19.143 | 36.647 | 1.00 | 29.61 | F | C |
| ATOM | 5935 | CG1 | ILE | F | 217 | −6.113 | 21.347 | 37.573 | 1.00 | 30.83 | F | C |
| ATOM | 5936 | CD1 | ILE | F | 217 | −5.960 | 22.581 | 36.706 | 1.00 | 29.40 | F | C |
| ATOM | 5937 | C | ILE | F | 217 | −4.082 | 18.156 | 36.944 | 1.00 | 36.99 | F | C |
| ATOM | 5938 | O | ILE | F | 217 | −3.399 | 18.335 | 35.923 | 1.00 | 36.82 | F | O |
| ATOM | 5939 | N | TYR | F | 218 | −4.359 | 16.954 | 37.439 | 1.00 | 38.63 | F | N |
| ATOM | 5940 | CA | TYR | F | 218 | −3.898 | 15.735 | 36.790 | 1.00 | 40.80 | F | C |
| ATOM | 5941 | CB | TYR | F | 218 | −3.091 | 14.882 | 37.766 | 1.00 | 33.98 | F | C |
| ATOM | 5942 | CG | TYR | F | 218 | −1.871 | 15.604 | 38.262 | 1.00 | 32.71 | F | C |
| ATOM | 5943 | CD1 | TYR | F | 218 | −0.663 | 15.516 | 37.576 | 1.00 | 32.84 | F | C |
| ATOM | 5944 | CE1 | TYR | F | 218 | 0.459 | 16.231 | 37.992 | 1.00 | 32.96 | F | C |
| ATOM | 5945 | CD2 | TYR | F | 218 | −1.934 | 16.426 | 39.391 | 1.00 | 33.08 | F | C |
| ATOM | 5946 | CE2 | TYR | F | 218 | −0.823 | 17.145 | 39.820 | 1.00 | 32.88 | F | C |
| ATOM | 5947 | CZ | TYR | F | 218 | 0.372 | 17.042 | 39.110 | 1.00 | 34.70 | F | C |
| ATOM | 5948 | OH | TYR | F | 218 | 1.482 | 17.759 | 39.497 | 1.00 | 36.96 | F | O |
| ATOM | 5949 | C | TYR | F | 218 | −5.122 | 14.987 | 36.296 | 1.00 | 44.33 | F | C |
| ATOM | 5950 | O | TYR | F | 218 | −6.088 | 14.775 | 37.041 | 1.00 | 42.47 | F | O |
| ATOM | 5951 | N | ALA | F | 219 | −5.082 | 14.622 | 35.018 | 1.00 | 50.15 | F | N |
| ATOM | 5952 | CA | ALA | F | 219 | −6.180 | 13.912 | 34.385 | 1.00 | 54.11 | F | C |
| ATOM | 5953 | CB | ALA | F | 219 | −5.773 | 13.448 | 32.973 | 1.00 | 53.97 | F | C |
| ATOM | 5954 | C | ALA | F | 219 | −6.566 | 12.722 | 35.243 | 1.00 | 56.02 | F | C |
| ATOM | 5955 | O | ALA | F | 219 | −5.706 | 11.932 | 35.629 | 1.00 | 57.08 | F | O |
| ATOM | 5956 | N | ASN | F | 220 | −7.858 | 12.636 | 35.552 | 1.00 | 59.23 | F | N |
| ATOM | 5957 | CA | ASN | F | 220 | −8.451 | 11.560 | 36.348 | 1.00 | 61.71 | F | C |
| ATOM | 5958 | CB | ASN | F | 220 | −9.650 | 10.963 | 35.583 | 1.00 | 62.99 | F | C |
| ATOM | 5959 | CG | ASN | F | 220 | −9.935 | 11.681 | 34.251 | 1.00 | 64.06 | F | C |
| ATOM | 5960 | OD1 | ASN | F | 220 | −11.078 | 12.054 | 33.970 | 1.00 | 65.94 | F | O |
| ATOM | 5961 | ND2 | ASN | F | 220 | −8.899 | 11.866 | 33.430 | 1.00 | 63.95 | F | N |
| ATOM | 5962 | C | ASN | F | 220 | −7.452 | 10.448 | 36.695 | 1.00 | 62.65 | F | C |
| ATOM | 5963 | O | ASN | F | 220 | −7.657 | 9.274 | 36.363 | 1.00 | 63.21 | F | O |
| ATOM | 5964 | N | GLU | F | 221 | −6.376 | 10.813 | 37.380 | 1.00 | 61.84 | F | N |
| ATOM | 5965 | CA | GLU | F | 221 | −5.373 | 9.825 | 37.710 | 1.00 | 61.53 | F | C |
| ATOM | 5966 | CB | GLU | F | 221 | −4.448 | 9.595 | 36.517 | 1.00 | 61.92 | F | C |
| ATOM | 5967 | CG | GLU | F | 221 | −4.427 | 8.183 | 36.009 | 1.00 | 65.17 | F | C |
| ATOM | 5968 | CD | GLU | F | 221 | −3.985 | 8.109 | 34.557 | 1.00 | 69.84 | F | C |
| ATOM | 5969 | OE1 | GLU | F | 221 | −2.795 | 7.795 | 34.300 | 1.00 | 71.47 | F | O |
| ATOM | 5970 | OE2 | GLU | F | 221 | −4.832 | 8.369 | 33.670 | 1.00 | 72.28 | F | O |
| ATOM | 5971 | C | GLU | F | 221 | −4.526 | 10.208 | 38.888 | 1.00 | 60.20 | F | C |
| ATOM | 5972 | O | GLU | F | 221 | −3.814 | 11.217 | 38.850 | 1.00 | 59.82 | F | O |
| ATOM | 5973 | N | ALA | F | 222 | −4.601 | 9.396 | 39.936 | 1.00 | 58.79 | F | N |
| ATOM | 5974 | CA | ALA | F | 222 | −3.769 | 9.621 | 41.096 | 1.00 | 59.45 | F | C |
| ATOM | 5975 | CB | ALA | F | 222 | −4.152 | 8.673 | 42.232 | 1.00 | 57.54 | F | C |
| ATOM | 5976 | C | ALA | F | 222 | −2.379 | 9.291 | 40.539 | 1.00 | 59.81 | F | C |
| ATOM | 5977 | O | ALA | F | 222 | −1.384 | 9.257 | 41.262 | 1.00 | 59.39 | F | O |
| ATOM | 5978 | N | ALA | F | 223 | −2.338 | 9.048 | 39.228 | 1.00 | 61.39 | F | N |
| ATOM | 5979 | CA | ALA | F | 223 | −1.102 | 8.765 | 38.509 | 1.00 | 63.70 | F | C |
| ATOM | 5980 | CB | ALA | F | 223 | −1.409 | 8.340 | 37.091 | 1.00 | 62.31 | F | C |
| ATOM | 5981 | C | ALA | F | 223 | −0.286 | 10.055 | 38.498 | 1.00 | 66.19 | F | C |
| ATOM | 5982 | O | ALA | F | 223 | 0.682 | 10.194 | 37.741 | 1.00 | 67.41 | F | O |
| ATOM | 5983 | N | ALA | F | 224 | −0.716 | 11.003 | 39.331 | 1.00 | 65.75 | F | N |
| ATOM | 5984 | CA | ALA | F | 224 | −0.047 | 12.280 | 39.496 | 1.00 | 63.35 | F | C |
| ATOM | 5985 | CB | ALA | F | 224 | −0.787 | 13.121 | 40.518 | 1.00 | 60.79 | F | C |
| ATOM | 5986 | C | ALA | F | 224 | 1.363 | 11.971 | 39.995 | 1.00 | 64.65 | F | C |
| ATOM | 5987 | O | ALA | F | 224 | 2.247 | 12.830 | 39.939 | 1.00 | 65.68 | F | O |
| ATOM | 5988 | N | GLY | F | 225 | 1.555 | 10.741 | 40.491 | 1.00 | 64.52 | F | N |
| ATOM | 5989 | CA | GLY | F | 225 | 2.857 | 10.304 | 40.978 | 1.00 | 63.86 | F | C |
| ATOM | 5990 | C | GLY | F | 225 | 3.899 | 10.693 | 39.946 | 1.00 | 65.59 | F | C |
| ATOM | 5991 | O | GLY | F | 225 | 4.978 | 11.201 | 40.280 | 1.00 | 66.03 | F | O |
| ATOM | 5992 | N | LYS | F | 226 | 3.578 | 10.435 | 38.681 | 1.00 | 65.32 | F | N |
| ATOM | 5993 | CA | LYS | F | 226 | 4.452 | 10.822 | 37.584 | 1.00 | 65.20 | F | C |
| ATOM | 5994 | CB | LYS | F | 226 | 4.271 | 9.886 | 36.384 | 1.00 | 66.35 | F | C |
| ATOM | 5995 | CG | LYS | F | 226 | 5.537 | 9.717 | 35.538 | 1.00 | 68.70 | F | C |
| ATOM | 5996 | CD | LYS | F | 226 | 6.665 | 9.033 | 36.318 | 1.00 | 69.90 | F | C |
| ATOM | 5997 | CE | LYS | F | 226 | 7.497 | 8.112 | 35.419 | 1.00 | 69.68 | F | C |
| ATOM | 5998 | NZ | LYS | F | 226 | 6.834 | 6.783 | 35.206 | 1.00 | 69.20 | F | N |
| ATOM | 5999 | C | LYS | F | 226 | 3.938 | 12.222 | 37.259 | 1.00 | 63.62 | F | C |
| ATOM | 6000 | O | LYS | F | 226 | 2.803 | 12.388 | 36.796 | 1.00 | 64.64 | F | O |
| ATOM | 6001 | N | ASP | F | 227 | 4.756 | 13.229 | 37.542 | 1.00 | 61.51 | F | N |
| ATOM | 6002 | CA | ASP | F | 227 | 4.365 | 14.613 | 37.306 | 1.00 | 58.38 | F | C |
| ATOM | 6003 | CB | ASP | F | 227 | 5.523 | 15.546 | 37.653 | 1.00 | 59.09 | F | C |
| ATOM | 6004 | CG | ASP | F | 227 | 5.098 | 16.674 | 38.569 | 1.00 | 62.58 | F | C |
| ATOM | 6005 | OD1 | ASP | F | 227 | 5.801 | 16.908 | 39.585 | 1.00 | 62.95 | F | O |
| ATOM | 6006 | OD2 | ASP | F | 227 | 4.060 | 17.320 | 38.270 | 1.00 | 60.79 | F | O |
| ATOM | 6007 | C | ASP | F | 227 | 3.902 | 14.876 | 35.876 | 1.00 | 55.09 | F | C |
| ATOM | 6008 | O | ASP | F | 227 | 4.666 | 15.369 | 35.042 | 1.00 | 55.33 | F | O |
| ATOM | 6009 | N | GLU | F | 228 | 2.642 | 14.560 | 35.601 | 1.00 | 50.79 | F | N |
| ATOM | 6010 | CA | GLU | F | 228 | 2.090 | 14.758 | 34.272 | 1.00 | 48.71 | F | C |
| ATOM | 6011 | CB | GLU | F | 228 | 2.002 | 13.411 | 33.550 | 1.00 | 48.21 | F | C |
| ATOM | 6012 | CG | GLU | F | 228 | 3.309 | 12.979 | 32.887 | 1.00 | 51.55 | F | C |
| ATOM | 6013 | CD | GLU | F | 228 | 3.520 | 11.465 | 32.900 | 1.00 | 54.38 | F | C |
| ATOM | 6014 | OE1 | GLU | F | 228 | 2.542 | 10.713 | 32.691 | 1.00 | 56.11 | F | O |
| ATOM | 6015 | OE2 | GLU | F | 228 | 4.669 | 11.021 | 33.117 | 1.00 | 55.57 | F | O |
| ATOM | 6016 | C | GLU | F | 228 | 0.714 | 15.419 | 34.346 | 1.00 | 46.69 | F | C |
| ATOM | 6017 | O | GLU | F | 228 | −0.317 | 14.778 | 34.120 | 1.00 | 48.90 | F | O |
| ATOM | 6018 | N | PRO | F | 229 | 0.678 | 16.717 | 34.669 | 1.00 | 43.30 | F | N |
| ATOM | 6019 | CD | PRO | F | 229 | 1.825 | 17.590 | 34.974 | 1.00 | 42.26 | F | C |
| ATOM | 6020 | CA | PRO | F | 229 | −0.600 | 17.431 | 34.762 | 1.00 | 40.89 | F | C |
| ATOM | 6021 | CB | PRO | F | 229 | −0.205 | 18.819 | 35.263 | 1.00 | 41.80 | F | C |
| ATOM | 6022 | CG | PRO | F | 229 | 1.237 | 18.973 | 34.868 | 1.00 | 39.39 | F | C |
| ATOM | 6023 | C | PRO | F | 229 | −1.309 | 17.510 | 33.427 | 1.00 | 40.29 | F | C |
| ATOM | 6024 | O | PRO | F | 229 | −0.705 | 17.274 | 32.385 | 1.00 | 40.03 | F | O |
| ATOM | 6025 | N | LYS | F | 230 | −2.597 | 17.839 | 33.463 | 1.00 | 40.94 | F | N |
| ATOM | 6026 | CA | LYS | F | 230 | −3.378 | 17.988 | 32.238 | 1.00 | 40.66 | F | C |
| ATOM | 6027 | CB | LYS | F | 230 | −4.830 | 18.359 | 32.565 | 1.00 | 41.67 | F | C |
| ATOM | 6028 | CG | LYS | F | 230 | −5.761 | 17.175 | 32.799 | 1.00 | 44.89 | F | C |
| ATOM | 6029 | CD | LYS | F | 230 | −6.223 | 16.569 | 31.477 | 1.00 | 47.37 | F | C |
| ATOM | 6030 | CE | LYS | F | 230 | −7.735 | 16.416 | 31.423 | 1.00 | 47.62 | F | C |
| ATOM | 6031 | NZ | LYS | F | 230 | −8.114 | 14.977 | 31.390 | 1.00 | 48.85 | F | N |
| ATOM | 6032 | C | LYS | F | 230 | −2.726 | 19.127 | 31.453 | 1.00 | 41.61 | F | C |
| ATOM | 6033 | O | LYS | F | 230 | −2.176 | 20.059 | 32.043 | 1.00 | 41.13 | F | O |
| ATOM | 6034 | N | PRO | F | 231 | −2.776 | 19.068 | 30.114 | 1.00 | 42.55 | F | N |
| ATOM | 6035 | CD | PRO | F | 231 | −3.380 | 18.018 | 29.275 | 1.00 | 42.73 | F | C |
| ATOM | 6036 | CA | PRO | F | 231 | −2.163 | 20.131 | 29.307 | 1.00 | 42.69 | F | C |
| ATOM | 6037 | CB | PRO | F | 231 | −2.580 | 19.785 | 27.882 | 1.00 | 43.44 | F | C |
| ATOM | 6038 | CG | PRO | F | 231 | −2.787 | 18.291 | 27.925 | 1.00 | 45.82 | F | C |
| ATOM | 6039 | C | PRO | F | 231 | −2.630 | 21.517 | 29.730 | 1.00 | 42.39 | F | C |
| ATOM | 6040 | O | PRO | F | 231 | −3.829 | 21.803 | 29.726 | 1.00 | 42.78 | F | O |
| ATOM | 6041 | N | LEU | F | 232 | −1.678 | 22.373 | 30.090 | 1.00 | 42.52 | F | N |
| ATOM | 6042 | CA | LEU | F | 232 | −1.995 | 23.729 | 30.538 | 1.00 | 41.75 | F | C |
| ATOM | 6043 | CB | LEU | F | 232 | −2.797 | 23.667 | 31.843 | 1.00 | 40.76 | F | C |
| ATOM | 6044 | CG | LEU | F | 232 | −3.633 | 24.869 | 32.283 | 1.00 | 40.06 | F | C |
| ATOM | 6045 | CD1 | LEU | F | 232 | −4.783 | 24.367 | 33.135 | 1.00 | 39.09 | F | C |
| ATOM | 6046 | CD2 | LEU | F | 232 | −2.786 | 25.849 | 33.075 | 1.00 | 38.69 | F | C |
| ATOM | 6047 | C | LEU | F | 232 | −0.709 | 24.511 | 30.777 | 1.00 | 41.46 | F | C |
| ATOM | 6048 | O | LEU | F | 232 | 0.308 | 23.937 | 31.183 | 1.00 | 40.73 | F | O |
| ATOM | 6049 | N | LEU | F | 233 | −0.753 | 25.816 | 30.516 | 1.00 | 41.86 | F | N |
| ATOM | 6050 | CA | LEU | F | 233 | 0.413 | 26.673 | 30.738 | 1.00 | 41.17 | F | C |
| ATOM | 6051 | CB | LEU | F | 233 | 0.363 | 27.905 | 29.826 | 1.00 | 43.18 | F | C |
| ATOM | 6052 | CG | LEU | F | 233 | −0.972 | 28.676 | 29.876 | 1.00 | 48.50 | F | C |
| ATOM | 6053 | CD1 | LEU | F | 233 | −0.753 | 30.154 | 29.485 | 1.00 | 48.82 | F | C |
| ATOM | 6054 | CD2 | LEU | F | 233 | −2.000 | 28.002 | 28.957 | 1.00 | 45.77 | F | C |
| ATOM | 6055 | C | LEU | F | 233 | 0.346 | 27.106 | 32.202 | 1.00 | 38.63 | F | C |
| ATOM | 6056 | O | LEU | F | 233 | −0.517 | 27.899 | 32.587 | 1.00 | 38.70 | F | O |
| ATOM | 6057 | N | TYR | F | 234 | 1.238 | 26.566 | 33.022 | 1.00 | 34.41 | F | N |
| ATOM | 6058 | CA | TYR | F | 234 | 1.245 | 26.914 | 34.432 | 1.00 | 31.29 | F | C |
| ATOM | 6059 | CB | TYR | F | 234 | 1.716 | 25.716 | 35.259 | 1.00 | 27.05 | F | C |
| ATOM | 6060 | CG | TYR | F | 234 | 0.651 | 24.655 | 35.414 | 1.00 | 28.10 | F | C |
| ATOM | 6061 | CD1 | TYR | F | 234 | 0.511 | 23.645 | 34.471 | 1.00 | 26.69 | F | C |
| ATOM | 6062 | CE1 | TYR | F | 234 | −0.492 | 22.688 | 34.587 | 1.00 | 30.07 | F | C |
| ATOM | 6063 | CD2 | TYR | F | 234 | −0.240 | 24.681 | 36.489 | 1.00 | 30.15 | F | C |
| ATOM | 6064 | CE2 | TYR | F | 234 | −1.251 | 23.727 | 36.617 | 1.00 | 30.22 | F | C |
| ATOM | 6065 | CZ | TYR | F | 234 | −1.371 | 22.732 | 35.658 | 1.00 | 31.64 | F | C |
| ATOM | 6066 | OH | TYR | F | 234 | −2.364 | 21.774 | 35.751 | 1.00 | 34.88 | F | O |
| ATOM | 6067 | C | TYR | F | 234 | 2.163 | 28.109 | 34.634 | 1.00 | 29.93 | F | C |
| ATOM | 6068 | O | TYR | F | 234 | 2.979 | 28.415 | 33.768 | 1.00 | 27.57 | F | O |
| ATOM | 6069 | N | PRO | F | 235 | 2.035 | 28.807 | 35.778 | 1.00 | 29.96 | F | N |
| ATOM | 6070 | CD | PRO | F | 235 | 1.101 | 28.564 | 36.893 | 1.00 | 30.30 | F | C |
| ATOM | 6071 | CA | PRO | F | 235 | 2.897 | 29.970 | 36.022 | 1.00 | 29.44 | F | C |
| ATOM | 6072 | CB | PRO | F | 235 | 2.409 | 30.524 | 37.368 | 1.00 | 28.09 | F | C |
| ATOM | 6073 | CG | PRO | F | 235 | 1.066 | 29.892 | 37.598 | 1.00 | 29.92 | F | C |
| ATOM | 6074 | C | PRO | F | 235 | 4.351 | 29.536 | 36.080 | 1.00 | 26.62 | F | C |
| ATOM | 6075 | O | PRO | F | 235 | 4.651 | 28.437 | 36.522 | 1.00 | 31.10 | F | O |
| ATOM | 6076 | N | ASN | F | 236 | 5.246 | 30.394 | 35.625 | 1.00 | 24.99 | F | N |
| ATOM | 6077 | CA | ASN | F | 236 | 6.668 | 30.099 | 35.644 | 1.00 | 25.77 | F | C |
| ATOM | 6078 | CB | ASN | F | 236 | 7.255 | 30.221 | 34.245 | 1.00 | 26.52 | F | C |
| ATOM | 6079 | CG | ASN | F | 236 | 8.721 | 29.865 | 34.207 | 1.00 | 30.49 | F | C |
| ATOM | 6080 | OD1 | ASN | F | 236 | 9.516 | 30.350 | 35.010 | 1.00 | 31.27 | F | O |
| ATOM | 6081 | ND2 | ASN | F | 236 | 9.090 | 29.006 | 33.269 | 1.00 | 37.45 | F | N |
| ATOM | 6082 | C | ASN | F | 236 | 7.334 | 31.106 | 36.563 | 1.00 | 26.25 | F | C |
| ATOM | 6083 | O | ASN | F | 236 | 7.524 | 32.262 | 36.183 | 1.00 | 26.43 | F | O |
| ATOM | 6084 | N | MET | F | 237 | 7.695 | 30.657 | 37.761 | 1.00 | 25.90 | F | N |
| ATOM | 6085 | CA | MET | F | 237 | 8.298 | 31.526 | 38.752 | 1.00 | 27.57 | F | C |
| ATOM | 6086 | CB | MET | F | 237 | 8.458 | 30.788 | 40.083 | 1.00 | 32.47 | F | C |
| ATOM | 6087 | CG | MET | F | 237 | 8.561 | 31.736 | 41.271 | 1.00 | 35.11 | F | C |
| ATOM | 6088 | SD | MET | F | 237 | 8.832 | 30.874 | 42.803 | 1.00 | 43.86 | F | S |
| ATOM | 6089 | CE | MET | F | 237 | 10.605 | 31.123 | 43.049 | 1.00 | 39.23 | F | C |
| ATOM | 6090 | C | MET | F | 237 | 9.624 | 32.142 | 38.361 | 1.00 | 26.86 | F | C |
| ATOM | 6091 | O | MET | F | 237 | 9.903 | 33.287 | 38.726 | 1.00 | 27.21 | F | O |
| ATOM | 6092 | N | GLU | F | 238 | 10.452 | 31.393 | 37.643 | 1.00 | 25.26 | F | N |
| ATOM | 6093 | CA | GLU | F | 238 | 11.747 | 31.917 | 37.228 | 1.00 | 26.99 | F | C |
| ATOM | 6094 | CB | GLU | F | 238 | 12.598 | 30.807 | 36.610 | 1.00 | 32.66 | F | C |
| ATOM | 6095 | CG | GLU | F | 238 | 14.087 | 31.102 | 36.612 | 1.00 | 43.77 | F | C |
| ATOM | 6096 | CD | GLU | F | 238 | 14.872 | 30.241 | 35.620 | 1.00 | 50.65 | F | C |
| ATOM | 6097 | OE1 | GLU | F | 238 | 15.936 | 30.705 | 35.133 | 1.00 | 54.22 | F | O |
| ATOM | 6098 | OE2 | GLU | F | 238 | 14.427 | 29.102 | 35.331 | 1.00 | 54.17 | F | O |
| ATOM | 6099 | C | GLU | F | 238 | 11.547 | 33.051 | 36.220 | 1.00 | 24.82 | F | C |
| ATOM | 6100 | O | GLU | F | 238 | 12.281 | 34.035 | 36.225 | 1.00 | 24.63 | F | O |
| ATOM | 6101 | N | GLU | F | 239 | 10.548 | 32.905 | 35.358 | 1.00 | 21.16 | F | N |
| ATOM | 6102 | CA | GLU | F | 239 | 10.249 | 33.925 | 34.375 | 1.00 | 21.08 | F | C |
| ATOM | 6103 | CB | GLU | F | 239 | 9.224 | 33.400 | 33.370 | 1.00 | 25.21 | F | C |
| ATOM | 6104 | CG | GLU | F | 239 | 8.894 | 34.375 | 32.238 | 1.00 | 28.84 | F | C |
| ATOM | 6105 | CD | GLU | F | 239 | 7.748 | 33.893 | 31.371 | 1.00 | 32.28 | F | C |
| ATOM | 6106 | OE1 | GLU | F | 239 | 7.112 | 34.737 | 30.704 | 1.00 | 35.32 | F | O |
| ATOM | 6107 | OE2 | GLU | F | 239 | 7.480 | 32.669 | 31.354 | 1.00 | 36.34 | F | O |
| ATOM | 6108 | C | GLU | F | 239 | 9.681 | 35.131 | 35.107 | 1.00 | 18.21 | F | C |
| ATOM | 6109 | O | GLU | F | 239 | 10.017 | 36.268 | 34.808 | 1.00 | 19.35 | F | O |
| ATOM | 6110 | N | PHE | F | 240 | 8.817 | 34.874 | 36.076 | 1.00 | 18.22 | F | N |
| ATOM | 6111 | CA | PHE | F | 240 | 8.211 | 35.950 | 36.848 | 1.00 | 18.53 | F | C |
| ATOM | 6112 | CB | PHE | F | 240 | 7.235 | 35.378 | 37.871 | 1.00 | 16.35 | F | C |
| ATOM | 6113 | CG | PHE | F | 240 | 6.567 | 36.426 | 38.703 | 1.00 | 19.77 | F | C |
| ATOM | 6114 | CD1 | PHE | F | 240 | 7.218 | 36.979 | 39.805 | 1.00 | 17.83 | F | C |
| ATOM | 6115 | CD2 | PHE | F | 240 | 5.289 | 36.877 | 38.381 | 1.00 | 19.18 | F | C |
| ATOM | 6116 | CE1 | PHE | F | 240 | 6.603 | 37.961 | 40.567 | 1.00 | 19.54 | F | C |
| ATOM | 6117 | CE2 | PHE | F | 240 | 4.667 | 37.862 | 39.143 | 1.00 | 20.14 | F | C |
| ATOM | 6118 | CZ | PHE | F | 240 | 5.324 | 38.402 | 40.235 | 1.00 | 19.26 | F | C |
| ATOM | 6119 | C | PHE | F | 240 | 9.264 | 36.781 | 37.564 | 1.00 | 19.64 | F | C |
| ATOM | 6120 | O | PHE | F | 240 | 9.240 | 38.016 | 37.518 | 1.00 | 19.62 | F | O |
| ATOM | 6121 | N | LEU | F | 241 | 10.191 | 36.091 | 38.226 | 1.00 | 21.44 | F | N |
| ATOM | 6122 | CA | LEU | F | 241 | 11.250 | 36.751 | 38.976 | 1.00 | 21.57 | F | C |
| ATOM | 6123 | CB | LEU | F | 241 | 12.043 | 35.716 | 39.786 | 1.00 | 21.06 | F | C |
| ATOM | 6124 | CG | LEU | F | 241 | 11.371 | 35.150 | 41.052 | 1.00 | 24.60 | F | C |
| ATOM | 6125 | CD1 | LEU | F | 241 | 12.128 | 33.897 | 41.525 | 1.00 | 22.80 | F | C |
| ATOM | 6126 | CD2 | LEU | F | 241 | 11.363 | 36.212 | 42.165 | 1.00 | 22.89 | F | C |
| ATOM | 6127 | C | LEU | F | 241 | 12.175 | 37.537 | 38.048 | 1.00 | 23.02 | F | C |
| ATOM | 6128 | O | LEU | F | 241 | 12.739 | 38.560 | 38.439 | 1.00 | 22.79 | F | O |
| ATOM | 6129 | N | ASP | F | 242 | 12.326 | 37.070 | 36.816 | 1.00 | 24.51 | F | N |
| ATOM | 6130 | CA | ASP | F | 242 | 13.176 | 37.772 | 35.861 | 1.00 | 25.76 | F | C |
| ATOM | 6131 | CB | ASP | F | 242 | 13.315 | 36.948 | 34.577 | 1.00 | 29.91 | F | C |
| ATOM | 6132 | CG | ASP | F | 242 | 14.232 | 35.744 | 34.747 | 1.00 | 36.44 | F | C |
| ATOM | 6133 | OD1 | ASP | F | 242 | 15.010 | 35.711 | 35.729 | 1.00 | 39.90 | F | O |
| ATOM | 6134 | OD2 | ASP | F | 242 | 14.176 | 34.825 | 33.894 | 1.00 | 42.14 | F | O |
| ATOM | 6135 | C | ASP | F | 242 | 12.554 | 39.130 | 35.534 | 1.00 | 22.17 | F | C |
| ATOM | 6136 | O | ASP | F | 242 | 13.234 | 40.151 | 35.522 | 1.00 | 21.50 | F | O |
| ATOM | 6137 | N | ASP | F | 243 | 11.250 | 39.112 | 35.267 | 1.00 | 22.07 | F | N |
| ATOM | 6138 | CA | ASP | F | 243 | 10.476 | 40.306 | 34.927 | 1.00 | 18.58 | F | C |
| ATOM | 6139 | CB | ASP | F | 243 | 9.068 | 39.896 | 34.481 | 1.00 | 16.18 | F | C |
| ATOM | 6140 | CG | ASP | F | 243 | 9.071 | 39.153 | 33.155 | 1.00 | 16.70 | F | C |
| ATOM | 6141 | OD1 | ASP | F | 243 | 10.017 | 39.356 | 32.372 | 1.00 | 17.19 | F | O |
| ATOM | 6142 | OD2 | ASP | F | 243 | 8.133 | 38.375 | 32.892 | 1.00 | 15.72 | F | O |
| ATOM | 6143 | C | ASP | F | 243 | 10.385 | 41.248 | 36.122 | 1.00 | 18.20 | F | C |
| ATOM | 6144 | O | ASP | F | 243 | 10.460 | 42.459 | 35.972 | 1.00 | 19.42 | F | O |
| ATOM | 6145 | N | MET | F | 244 | 10.214 | 40.683 | 37.309 | 1.00 | 18.12 | F | N |
| ATOM | 6146 | CA | MET | F | 244 | 10.132 | 41.477 | 38.531 | 1.00 | 19.50 | F | C |
| ATOM | 6147 | CB | MET | F | 244 | 9.836 | 40.565 | 39.724 | 1.00 | 17.56 | F | C |
| ATOM | 6148 | CG | MET | F | 244 | 9.773 | 41.263 | 41.060 | 1.00 | 20.16 | F | C |
| ATOM | 6149 | SD | MET | F | 244 | 9.859 | 40.077 | 42.458 | 1.00 | 24.61 | F | S |
| ATOM | 6150 | CE | MET | F | 244 | 11.626 | 39.806 | 42.550 | 1.00 | 19.46 | F | C |
| ATOM | 6151 | C | MET | F | 244 | 11.447 | 42.225 | 38.761 | 1.00 | 19.21 | F | C |
| ATOM | 6152 | O | MET | F | 244 | 11.453 | 43.429 | 39.037 | 1.00 | 19.11 | F | O |
| ATOM | 6153 | N | ASN | F | 245 | 12.563 | 41.512 | 38.648 | 1.00 | 19.67 | F | N |
| ATOM | 6154 | CA | ASN | F | 245 | 13.875 | 42.130 | 38.831 | 1.00 | 20.69 | F | C |
| ATOM | 6155 | CB | ASN | F | 245 | 14.978 | 41.078 | 38.712 | 1.00 | 19.64 | F | C |
| ATOM | 6156 | CG | ASN | F | 245 | 15.072 | 40.209 | 39.943 | 1.00 | 24.77 | F | C |
| ATOM | 6157 | OD1 | ASN | F | 245 | 15.040 | 40.705 | 41.070 | 1.00 | 25.45 | F | O |
| ATOM | 6158 | ND2 | ASN | F | 245 | 15.181 | 38.906 | 39.740 | 1.00 | 25.76 | F | N |
| ATOM | 6159 | C | ASN | F | 245 | 14.115 | 43.249 | 37.820 | 1.00 | 20.99 | F | C |
| ATOM | 6160 | O | ASN | F | 245 | 14.730 | 44.262 | 38.145 | 1.00 | 21.28 | F | O |
| ATOM | 6161 | N | PHE | F | 246 | 13.632 | 43.055 | 36.594 | 1.00 | 21.99 | F | N |
| ATOM | 6162 | CA | PHE | F | 246 | 13.780 | 44.060 | 35.544 | 1.00 | 20.53 | F | C |
| ATOM | 6163 | CB | PHE | F | 246 | 13.236 | 43.533 | 34.215 | 1.00 | 18.93 | F | C |
| ATOM | 6164 | CG | PHE | F | 246 | 12.901 | 44.617 | 33.247 | 1.00 | 22.32 | F | C |
| ATOM | 6165 | CD1 | PHE | F | 246 | 11.597 | 45.077 | 33.120 | 1.00 | 21.81 | F | C |
| ATOM | 6166 | CD2 | PHE | F | 246 | 13.904 | 45.231 | 32.505 | 1.00 | 23.30 | F | C |
| ATOM | 6167 | CE1 | PHE | F | 246 | 11.291 | 46.140 | 32.272 | 1.00 | 20.07 | F | C |
| ATOM | 6168 | CE2 | PHE | F | 246 | 13.604 | 46.297 | 31.652 | 1.00 | 23.81 | F | C |
| ATOM | 6169 | CZ | PHE | F | 246 | 12.290 | 46.749 | 31.541 | 1.00 | 21.14 | F | C |
| ATOM | 6170 | C | PHE | F | 246 | 13.013 | 45.331 | 35.918 | 1.00 | 19.27 | F | C |
| ATOM | 6171 | O | PHE | F | 246 | 13.499 | 46.442 | 35.733 | 1.00 | 22.16 | F | O |
| ATOM | 6172 | N | LEU | F | 247 | 11.804 | 45.158 | 36.433 | 1.00 | 17.79 | F | N |
| ATOM | 6173 | CA | LEU | F | 247 | 10.984 | 46.293 | 36.807 | 1.00 | 16.52 | F | C |
| ATOM | 6174 | CB | LEU | F | 247 | 9.567 | 45.820 | 37.105 | 1.00 | 13.93 | F | C |
| ATOM | 6175 | CG | LEU | F | 247 | 8.722 | 45.426 | 35.881 | 1.00 | 16.55 | F | C |
| ATOM | 6176 | CD1 | LEU | F | 247 | 7.419 | 44.779 | 36.387 | 1.00 | 14.27 | F | C |
| ATOM | 6177 | CD2 | LEU | F | 247 | 8.405 | 46.657 | 35.005 | 1.00 | 9.93 | F | C |
| ATOM | 6178 | C | LEU | F | 247 | 11.587 | 47.005 | 38.009 | 1.00 | 18.85 | F | C |
| ATOM | 6179 | O | LEU | F | 247 | 11.560 | 48.237 | 38.104 | 1.00 | 19.60 | F | O |
| ATOM | 6180 | N | LEU | F | 248 | 12.146 | 46.225 | 38.925 | 1.00 | 20.77 | F | N |
| ATOM | 6181 | CA | LEU | F | 248 | 12.770 | 46.797 | 40.101 | 1.00 | 20.77 | F | C |
| ATOM | 6182 | CB | LEU | F | 248 | 13.302 | 45.689 | 41.001 | 1.00 | 23.51 | F | C |
| ATOM | 6183 | CG | LEU | F | 248 | 12.591 | 45.447 | 42.335 | 1.00 | 27.13 | F | C |
| ATOM | 6184 | CD1 | LEU | F | 248 | 11.172 | 45.988 | 42.308 | 1.00 | 28.20 | F | C |
| ATOM | 6185 | CD2 | LEU | F | 248 | 12.590 | 43.957 | 42.607 | 1.00 | 26.74 | F | C |
| ATOM | 6186 | C | LEU | F | 248 | 13.913 | 47.686 | 39.637 | 1.00 | 21.48 | F | C |
| ATOM | 6187 | O | LEU | F | 248 | 14.064 | 48.815 | 40.096 | 1.00 | 24.72 | F | O |
| ATOM | 6188 | N | ALA | F | 249 | 14.720 | 47.189 | 38.713 | 1.00 | 19.71 | F | N |
| ATOM | 6189 | CA | ALA | F | 249 | 15.825 | 47.992 | 38.206 | 1.00 | 20.43 | F | C |
| ATOM | 6190 | CB | ALA | F | 249 | 16.670 | 47.161 | 37.244 | 1.00 | 16.64 | F | C |
| ATOM | 6191 | C | ALA | F | 249 | 15.277 | 49.236 | 37.496 | 1.00 | 21.20 | F | C |
| ATOM | 6192 | O | ALA | F | 249 | 15.691 | 50.365 | 37.772 | 1.00 | 22.66 | F | O |
| ATOM | 6193 | N | LEU | F | 250 | 14.321 | 49.021 | 36.598 | 1.00 | 20.58 | F | N |
| ATOM | 6194 | CA | LEU | F | 250 | 13.722 | 50.103 | 35.828 | 1.00 | 20.44 | F | C |
| ATOM | 6195 | CB | LEU | F | 250 | 12.555 | 49.563 | 34.999 | 1.00 | 17.53 | F | C |
| ATOM | 6196 | CG | LEU | F | 250 | 11.874 | 50.627 | 34.148 | 1.00 | 17.23 | F | C |
| ATOM | 6197 | CD1 | LEU | F | 250 | 12.766 | 50.920 | 32.975 | 1.00 | 16.13 | F | C |
| ATOM | 6198 | CD2 | LEU | F | 250 | 10.492 | 50.150 | 33.680 | 1.00 | 20.07 | F | C |
| ATOM | 6199 | C | LEU | F | 250 | 13.242 | 51.298 | 36.654 | 1.00 | 21.36 | F | C |
| ATOM | 6200 | O | LEU | F | 250 | 13.620 | 52.436 | 36.382 | 1.00 | 21.43 | F | O |
| ATOM | 6201 | N | ILE | F | 251 | 12.412 | 51.048 | 37.662 | 1.00 | 21.93 | F | N |
| ATOM | 6202 | CA | ILE | F | 251 | 11.883 | 52.142 | 38.464 | 1.00 | 22.25 | F | C |
| ATOM | 6203 | CB | ILE | F | 251 | 10.760 | 51.653 | 39.430 | 1.00 | 22.89 | F | C |
| ATOM | 6204 | CG2 | ILE | F | 251 | 9.708 | 50.864 | 38.664 | 1.00 | 21.04 | F | C |
| ATOM | 6205 | CG1 | ILE | F | 251 | 11.340 | 50.768 | 40.526 | 1.00 | 23.96 | F | C |
| ATOM | 6206 | CD1 | ILE | F | 251 | 10.274 | 50.210 | 41.479 | 1.00 | 24.36 | F | C |
| ATOM | 6207 | C | ILE | F | 251 | 12.939 | 52.908 | 39.254 | 1.00 | 23.71 | F | C |
| ATOM | 6208 | O | ILE | F | 251 | 12.683 | 54.013 | 39.746 | 1.00 | 24.85 | F | O |
| ATOM | 6209 | N | ALA | F | 252 | 14.130 | 52.339 | 39.373 | 1.00 | 23.53 | F | N |
| ATOM | 6210 | CA | ALA | F | 252 | 15.179 | 53.027 | 40.103 | 1.00 | 24.64 | F | C |
| ATOM | 6211 | CB | ALA | F | 252 | 15.925 | 52.044 | 40.981 | 1.00 | 23.99 | F | C |
| ATOM | 6212 | C | ALA | F | 252 | 16.156 | 53.745 | 39.175 | 1.00 | 25.78 | F | C |
| ATOM | 6213 | O | ALA | F | 252 | 17.040 | 54.463 | 39.648 | 1.00 | 27.36 | F | O |
| ATOM | 6214 | N | GLN | F | 253 | 15.996 | 53.552 | 37.866 | 1.00 | 24.53 | F | N |
| ATOM | 6215 | CA | GLN | F | 253 | 16.871 | 54.161 | 36.865 | 1.00 | 22.97 | F | C |
| ATOM | 6216 | CB | GLN | F | 253 | 16.591 | 53.560 | 35.501 | 1.00 | 28.98 | F | C |
| ATOM | 6217 | CG | GLN | F | 253 | 17.753 | 52.831 | 34.886 | 1.00 | 33.95 | F | C |
| ATOM | 6218 | CD | GLN | F | 253 | 17.288 | 51.893 | 33.797 | 1.00 | 38.75 | F | C |
| ATOM | 6219 | OE1 | GLN | F | 253 | 17.459 | 50.675 | 33.895 | 1.00 | 44.26 | F | O |
| ATOM | 6220 | NE2 | GLN | F | 253 | 16.685 | 52.455 | 32.745 | 1.00 | 42.54 | F | N |
| ATOM | 6221 | C | GLN | F | 253 | 16.721 | 55.663 | 36.756 | 1.00 | 22.65 | F | C |
| ATOM | 6222 | O | GLN | F | 253 | 15.639 | 56.168 | 36.457 | 1.00 | 24.79 | F | O |
| ATOM | 6223 | N | GLY | F | 254 | 17.824 | 56.369 | 36.966 | 1.00 | 21.59 | F | N |
| ATOM | 6224 | CA | GLY | F | 254 | 17.817 | 57.814 | 36.899 | 1.00 | 20.14 | F | C |
| ATOM | 6225 | C | GLY | F | 254 | 17.118 | 58.415 | 35.698 | 1.00 | 21.85 | F | C |
| ATOM | 6226 | O | GLY | F | 254 | 16.174 | 59.188 | 35.862 | 1.00 | 25.19 | F | O |
| ATOM | 6227 | N | PRO | F | 255 | 17.560 | 58.095 | 34.473 | 1.00 | 21.40 | F | N |
| ATOM | 6228 | CD | PRO | F | 255 | 18.690 | 57.216 | 34.140 | 1.00 | 19.30 | F | C |
| ATOM | 6229 | CA | PRO | F | 255 | 16.921 | 58.649 | 33.276 | 1.00 | 20.25 | F | C |
| ATOM | 6230 | CB | PRO | F | 255 | 17.716 | 58.028 | 32.130 | 1.00 | 21.87 | F | C |
| ATOM | 6231 | CG | PRO | F | 255 | 19.054 | 57.672 | 32.772 | 1.00 | 23.32 | F | C |
| ATOM | 6232 | C | PRO | F | 255 | 15.421 | 58.366 | 33.166 | 1.00 | 19.85 | F | C |
| ATOM | 6233 | O | PRO | F | 255 | 14.656 | 59.218 | 32.716 | 1.00 | 20.33 | F | O |
| ATOM | 6234 | N | VAL | F | 256 | 14.995 | 57.173 | 33.567 | 1.00 | 18.72 | F | N |
| ATOM | 6235 | CA | VAL | F | 256 | 13.575 | 56.829 | 33.485 | 1.00 | 17.47 | F | C |
| ATOM | 6236 | CB | VAL | F | 256 | 13.358 | 55.325 | 33.732 | 1.00 | 15.84 | F | C |
| ATOM | 6237 | CG1 | VAL | F | 256 | 11.910 | 54.978 | 33.538 | 1.00 | 12.93 | F | C |
| ATOM | 6238 | CG2 | VAL | F | 256 | 14.220 | 54.513 | 32.763 | 1.00 | 14.76 | F | C |
| ATOM | 6239 | C | VAL | F | 256 | 12.782 | 57.661 | 34.505 | 1.00 | 19.27 | F | C |
| ATOM | 6240 | O | VAL | F | 256 | 11.666 | 58.131 | 34.237 | 1.00 | 20.42 | F | O |
| ATOM | 6241 | N | LYS | F | 257 | 13.369 | 57.862 | 35.676 | 1.00 | 18.71 | F | N |
| ATOM | 6242 | CA | LYS | F | 257 | 12.728 | 58.661 | 36.711 | 1.00 | 19.06 | F | C |
| ATOM | 6243 | CB | LYS | F | 257 | 13.571 | 58.606 | 37.980 | 1.00 | 21.72 | F | C |
| ATOM | 6244 | CG | LYS | F | 257 | 13.098 | 57.571 | 38.961 | 1.00 | 24.33 | F | C |
| ATOM | 6245 | CD | LYS | F | 257 | 14.251 | 56.861 | 39.581 | 1.00 | 26.87 | F | C |
| ATOM | 6246 | CE | LYS | F | 257 | 14.605 | 57.473 | 40.911 | 1.00 | 28.28 | F | C |
| ATOM | 6247 | NZ | LYS | F | 257 | 16.028 | 57.147 | 41.271 | 1.00 | 35.80 | F | N |
| ATOM | 6248 | C | LYS | F | 257 | 12.584 | 60.106 | 36.232 | 1.00 | 17.31 | F | C |
| ATOM | 6249 | O | LYS | F | 257 | 11.536 | 60.722 | 36.404 | 1.00 | 17.94 | F | O |
| ATOM | 6250 | N | THR | F | 258 | 13.646 | 60.639 | 35.630 | 1.00 | 16.48 | F | N |
| ATOM | 6251 | CA | THE | F | 258 | 13.636 | 62.002 | 35.091 | 1.00 | 17.01 | F | C |
| ATOM | 6252 | CB | THR | F | 258 | 15.010 | 62.368 | 34.462 | 1.00 | 18.57 | F | C |
| ATOM | 6253 | OG1 | THR | F | 258 | 16.021 | 62.322 | 35.475 | 1.00 | 25.12 | F | O |
| ATOM | 6254 | CG2 | THR | F | 258 | 14.977 | 63.767 | 33.870 | 1.00 | 17.92 | F | C |
| ATOM | 6255 | C | THR | F | 258 | 12.568 | 62.178 | 34.012 | 1.00 | 15.30 | F | C |
| ATOM | 6256 | O | THR | F | 258 | 11.766 | 63.104 | 34.059 | 1.00 | 16.47 | F | O |
| ATOM | 6257 | N | TYR | F | 259 | 12.559 | 61.280 | 33.036 | 1.00 | 13.93 | F | N |
| ATOM | 6258 | CA | TYR | F | 259 | 11.599 | 61.375 | 31.952 | 1.00 | 12.35 | F | C |
| ATOM | 6259 | CB | TYR | F | 259 | 11.841 | 60.248 | 30.932 | 1.00 | 13.64 | F | C |
| ATOM | 6260 | CG | TYR | F | 259 | 10.867 | 60.242 | 29.764 | 1.00 | 14.52 | F | C |
| ATOM | 6261 | CD1 | TYR | F | 259 | 9.809 | 59.337 | 29.719 | 1.00 | 16.80 | F | C |
| ATOM | 6262 | CE1 | TYR | F | 259 | 8.904 | 59.336 | 28.642 | 1.00 | 19.86 | F | C |
| ATOM | 6263 | CD2 | TYR | F | 259 | 11.003 | 61.143 | 28.708 | 1.00 | 16.66 | F | C |
| ATOM | 6264 | CE2 | TYR | F | 259 | 10.107 | 61.153 | 27.631 | 1.00 | 14.07 | F | C |
| ATOM | 6265 | CZ | TYR | F | 259 | 9.063 | 60.254 | 27.604 | 1.00 | 17.91 | F | C |
| ATOM | 6266 | OH | TYR | F | 259 | 8.146 | 60.295 | 26.570 | 1.00 | 18.69 | F | O |
| ATOM | 6267 | C | TYR | F | 259 | 10.169 | 61.315 | 32.451 | 1.00 | 12.05 | F | C |
| ATOM | 6268 | O | TYR | F | 259 | 9.375 | 62.220 | 32.206 | 1.00 | 13.58 | F | O |
| ATOM | 6269 | N | THR | F | 260 | 9.839 | 60.242 | 33.158 | 1.00 | 12.94 | F | N |
| ATOM | 6270 | CA | THR | F | 260 | 8.480 | 60.059 | 33.629 | 1.00 | 14.47 | F | C |
| ATOM | 6271 | CB | THR | F | 260 | 8.326 | 58.689 | 34.325 | 1.00 | 16.45 | F | C |
| ATOM | 6272 | OG1 | THR | F | 260 | 9.242 | 58.595 | 35.429 | 1.00 | 20.16 | F | O |
| ATOM | 6273 | CG2 | THR | F | 260 | 8.617 | 57.562 | 33.328 | 1.00 | 11.28 | F | C |
| ATOM | 6274 | C | THR | F | 260 | 8.021 | 61.187 | 34.536 | 1.00 | 14.98 | F | C |
| ATOM | 6275 | O | THR | F | 260 | 6.860 | 61.565 | 34.503 | 1.00 | 14.76 | F | O |
| ATOM | 6276 | N | HIS | F | 261 | 8.933 | 61.738 | 35.335 | 1.00 | 18.69 | F | N |
| ATOM | 6277 | CA | HIS | F | 261 | 8.592 | 62.846 | 36.228 | 1.00 | 17.59 | F | C |
| ATOM | 6278 | CB | HIS | F | 261 | 9.800 | 63.232 | 37.089 | 1.00 | 21.96 | F | C |
| ATOM | 6279 | CG | HIS | F | 261 | 9.520 | 64.332 | 38.074 | 1.00 | 24.82 | F | C |
| ATOM | 6280 | CD2 | HIS | F | 261 | 8.767 | 64.352 | 39.200 | 1.00 | 22.31 | F | C |
| ATOM | 6281 | ND1 | HIS | F | 261 | 10.043 | 65.603 | 37.942 | 1.00 | 24.53 | F | N |
| ATOM | 6282 | CE1 | HIS | F | 261 | 9.625 | 66.356 | 38.945 | 1.00 | 22.78 | F | C |
| ATOM | 6283 | NE2 | HIS | F | 261 | 8.849 | 65.621 | 39.720 | 1.00 | 22.40 | F | N |
| ATOM | 6284 | C | HIS | F | 261 | 8.156 | 64.046 | 35.393 | 1.00 | 16.93 | F | C |
| ATOM | 6285 | O | HIS | F | 261 | 7.166 | 64.719 | 35.705 | 1.00 | 16.41 | F | O |
| ATOM | 6286 | N | ARG | F | 262 | 8.895 | 64.313 | 34.325 | 1.00 | 16.19 | F | N |
| ATOM | 6287 | CA | ARG | F | 262 | 8.562 | 65.434 | 33.451 | 1.00 | 15.99 | F | C |
| ATOM | 6288 | CB | ARG | F | 262 | 9.679 | 65.634 | 32.425 | 1.00 | 18.71 | F | C |
| ATOM | 6289 | CG | ARG | F | 262 | 9.789 | 67.047 | 31.865 | 1.00 | 28.43 | F | C |
| ATOM | 6290 | CD | ARG | F | 262 | 10.693 | 67.089 | 30.622 | 1.00 | 32.62 | F | C |
| ATOM | 6291 | NE | ARG | F | 262 | 11.973 | 66.416 | 30.853 | 1.00 | 39.96 | F | N |
| ATOM | 6292 | CZ | ARG | F | 262 | 12.354 | 65.291 | 30.251 | 1.00 | 40.26 | F | C |
| ATOM | 6293 | NH1 | ARG | F | 262 | 11.551 | 64.704 | 29.375 | 1.00 | 42.25 | F | N |
| ATOM | 6294 | NH2 | ARG | F | 262 | 13.533 | 64.740 | 30.535 | 1.00 | 43.09 | F | N |
| ATOM | 6295 | C | ARG | F | 262 | 7.210 | 65.217 | 32.752 | 1.00 | 12.02 | F | C |
| ATOM | 6296 | O | ARG | F | 262 | 6.378 | 66.125 | 32.710 | 1.00 | 15.74 | F | O |
| ATOM | 6297 | N | ARG | F | 263 | 6.968 | 64.014 | 32.233 | 1.00 | 10.83 | F | N |
| ATOM | 6298 | CA | ARG | F | 263 | 5.705 | 63.748 | 31.549 | 1.00 | 8.56 | F | C |
| ATOM | 6299 | CB | ARG | F | 263 | 5.715 | 62.337 | 30.942 | 1.00 | 6.96 | F | C |
| ATOM | 6300 | CG | ARG | F | 263 | 6.792 | 62.074 | 29.863 | 1.00 | 7.79 | F | C |
| ATOM | 6301 | CD | ARG | F | 263 | 6.911 | 63.208 | 28.855 | 1.00 | 6.43 | F | C |
| ATOM | 6302 | NE | ARG | F | 263 | 5.622 | 63.558 | 28.253 | 1.00 | 8.57 | F | N |
| ATOM | 6303 | CZ | ARG | F | 263 | 5.387 | 64.704 | 27.603 | 1.00 | 12.13 | F | C |
| ATOM | 6304 | NH1 | ARG | F | 263 | 6.353 | 65.602 | 27.472 | 1.00 | 9.28 | F | N |
| ATOM | 6305 | NH2 | ARG | F | 263 | 4.193 | 64.959 | 27.073 | 1.00 | 7.71 | F | N |
| ATOM | 6306 | C | ARG | F | 263 | 4.497 | 63.915 | 32.494 | 1.00 | 11.43 | F | C |
| ATOM | 6307 | O | ARG | F | 263 | 3.441 | 64.409 | 32.092 | 1.00 | 12.65 | F | O |
| ATOM | 6308 | N | LEU | F | 264 | 4.660 | 63.520 | 33.758 | 1.00 | 12.10 | F | N |
| ATOM | 6309 | CA | LEU | F | 264 | 3.576 | 63.633 | 34.735 | 1.00 | 11.78 | F | C |
| ATOM | 6310 | CB | LEU | F | 264 | 3.947 | 62.897 | 36.034 | 1.00 | 9.44 | F | C |
| ATOM | 6311 | CG | LEU | F | 264 | 3.914 | 61.365 | 35.929 | 1.00 | 10.10 | F | C |
| ATOM | 6312 | CD1 | LEU | F | 264 | 4.693 | 60.716 | 37.071 | 1.00 | 9.40 | F | C |
| ATOM | 6313 | CD2 | LEU | F | 264 | 2.474 | 60.898 | 35.924 | 1.00 | 5.42 | F | C |
| ATOM | 6314 | C | LEU | F | 264 | 3.258 | 65.102 | 35.010 | 1.00 | 9.98 | F | C |
| ATOM | 6315 | O | LEU | F | 264 | 2.089 | 65.485 | 35.142 | 1.00 | 7.73 | F | O |
| ATOM | 6316 | N | LYS | F | 265 | 4.302 | 65.925 | 35.086 | 1.00 | 12.43 | F | N |
| ATOM | 6317 | CA | LYS | F | 265 | 4.132 | 67.366 | 35.295 | 1.00 | 12.48 | F | C |
| ATOM | 6318 | CB | LYS | F | 265 | 5.491 | 68.056 | 35.415 | 1.00 | 15.54 | F | C |
| ATOM | 6319 | CG | LYS | F | 265 | 6.099 | 68.018 | 36.824 | 1.00 | 21.21 | F | C |
| ATOM | 6320 | CD | LYS | F | 265 | 7.622 | 68.288 | 36.808 | 1.00 | 27.36 | F | C |
| ATOM | 6321 | CE | LYS | F | 265 | 7.957 | 69.725 | 36.382 | 1.00 | 31.13 | F | C |
| ATOM | 6322 | NZ | LYS | F | 265 | 9.420 | 69.944 | 36.103 | 1.00 | 34.74 | F | N |
| ATOM | 6323 | C | LYS | F | 265 | 3.385 | 67.939 | 34.090 | 1.00 | 13.71 | F | C |
| ATOM | 6324 | O | LYS | F | 265 | 2.497 | 68.776 | 34.242 | 1.00 | 15.06 | F | O |
| ATOM | 6325 | N | PHE | F | 266 | 3.740 | 67.479 | 32.889 | 1.00 | 14.34 | F | N |
| ATOM | 6326 | CA | PHE | F | 266 | 3.068 | 67.955 | 31.682 | 1.00 | 11.91 | F | C |
| ATOM | 6327 | CB | PHE | F | 266 | 3.716 | 67.364 | 30.409 | 1.00 | 11.52 | F | C |
| ATOM | 6328 | CG | PHE | F | 266 | 3.022 | 67.785 | 29.136 | 1.00 | 11.90 | F | C |
| ATOM | 6329 | CD1 | PHE | F | 266 | 3.163 | 69.087 | 28.648 | 1.00 | 11.17 | F | C |
| ATOM | 6330 | CD2 | PHE | F | 266 | 2.144 | 66.907 | 28.477 | 1.00 | 11.91 | F | C |
| ATOM | 6331 | CE1 | PHE | F | 266 | 2.421 | 69.530 | 27.506 | 1.00 | 13.64 | F | C |
| ATOM | 6332 | CE2 | PHE | F | 266 | 1.403 | 67.328 | 27.340 | 1.00 | 14.53 | F | C |
| ATOM | 6333 | CZ | PHE | F | 266 | 1.542 | 68.651 | 26.856 | 1.00 | 12.77 | F | C |
| ATOM | 6334 | C | PHE | F | 266 | 1.587 | 67.578 | 31.741 | 1.00 | 10.30 | F | C |
| ATOM | 6335 | O | PHE | F | 266 | 0.722 | 68.416 | 31.509 | 1.00 | 11.90 | F | O |
| ATOM | 6336 | N | LEU | F | 267 | 1.302 | 66.317 | 32.057 | 1.00 | 9.84 | F | N |
| ATOM | 6337 | CA | LEU | F | 267 | −0.076 | 65.825 | 32.151 | 1.00 | 10.82 | F | C |
| ATOM | 6338 | CB | LEU | F | 267 | −0.070 | 64.386 | 32.678 | 1.00 | 11.78 | F | C |
| ATOM | 6339 | CG | LEU | F | 267 | −0.341 | 63.175 | 31.764 | 1.00 | 14.86 | F | C |
| ATOM | 6340 | CD1 | LEU | F | 267 | −0.208 | 63.535 | 30.301 | 1.00 | 14.83 | F | C |
| ATOM | 6341 | CD2 | LEU | F | 267 | 0.620 | 62.072 | 32.120 | 1.00 | 9.86 | F | C |
| ATOM | 6342 | C | LEU | F | 267 | −0.924 | 66.701 | 33.077 | 1.00 | 11.36 | F | C |
| ATOM | 6343 | O | LEU | F | 267 | −2.088 | 67.003 | 32.806 | 1.00 | 9.07 | F | O |
| ATOM | 6344 | N | SER | F | 268 | −0.317 | 67.107 | 34.185 | 1.00 | 11.99 | F | N |
| ATOM | 6345 | CA | SER | F | 268 | −0.981 | 67.937 | 35.164 | 1.00 | 7.72 | F | C |
| ATOM | 6346 | CB | SER | F | 268 | −0.123 | 67.980 | 36.434 | 1.00 | 10.36 | F | C |
| ATOM | 6347 | OG | SER | F | 268 | −0.578 | 68.977 | 37.338 | 1.00 | 10.89 | F | O |
| ATOM | 6348 | C | SER | F | 268 | −1.235 | 69.352 | 34.634 | 1.00 | 9.59 | F | C |
| ATOM | 6349 | O | SER | F | 268 | −2.364 | 69.855 | 34.721 | 1.00 | 9.02 | F | O |
| ATOM | 6350 | N | SER | F | 269 | −0.201 | 70.008 | 34.103 | 1.00 | 8.65 | F | N |
| ATOM | 6351 | CA | SER | F | 269 | −0.382 | 71.359 | 33.560 | 1.00 | 10.54 | F | C |
| ATOM | 6352 | CB | SER | F | 269 | 0.955 | 71.952 | 33.137 | 1.00 | 12.03 | F | C |
| ATOM | 6353 | OG | SER | F | 269 | 1.804 | 72.144 | 34.244 | 1.00 | 12.84 | F | O |
| ATOM | 6354 | C | SER | F | 269 | −1.328 | 71.371 | 32.351 | 1.00 | 10.28 | F | C |
| ATOM | 6355 | O | SER | F | 269 | −2.154 | 72.282 | 32.214 | 1.00 | 11.78 | F | O |
| ATOM | 6356 | N | LYS | F | 270 | −1.211 | 70.369 | 31.473 | 1.00 | 10.70 | F | N |
| ATOM | 6357 | CA | LYS | F | 270 | −2.079 | 70.315 | 30.305 | 1.00 | 10.59 | F | C |
| ATOM | 6358 | CB | LYS | F | 270 | −1.797 | 69.071 | 29.447 | 1.00 | 9.36 | F | C |
| ATOM | 6359 | CG | LYS | F | 270 | −2.342 | 69.207 | 27.988 | 1.00 | 12.31 | F | C |
| ATOM | 6360 | CD | LYS | F | 270 | −2.377 | 67.895 | 27.203 | 1.00 | 5.97 | F | C |
| ATOM | 6361 | CE | LYS | F | 270 | −3.156 | 68.063 | 25.901 | 1.00 | 11.99 | F | C |
| ATOM | 6362 | NZ | LYS | F | 270 | −3.391 | 66.763 | 25.187 | 1.00 | 11.54 | F | N |
| ATOM | 6363 | C | LYS | F | 270 | −3.535 | 70.318 | 30.732 | 1.00 | 10.71 | F | C |
| ATOM | 6364 | O | LYS | F | 270 | −4.362 | 71.006 | 30.138 | 1.00 | 12.97 | F | O |
| ATOM | 6365 | N | PHE | F | 271 | −3.860 | 69.557 | 31.770 | 1.00 | 13.09 | F | N |
| ATOM | 6366 | CA | PHE | F | 271 | −5.243 | 69.509 | 32.219 | 1.00 | 12.53 | F | C |
| ATOM | 6367 | CB | PHE | F | 271 | −5.450 | 68.456 | 33.298 | 1.00 | 12.55 | F | C |
| ATOM | 6368 | CG | PHE | F | 271 | −6.887 | 68.299 | 33.691 | 1.00 | 11.41 | F | C |
| ATOM | 6369 | CD1 | PHE | F | 271 | −7.755 | 67.532 | 32.908 | 1.00 | 10.06 | F | C |
| ATOM | 6370 | CD2 | PHE | F | 271 | −7.396 | 68.960 | 34.809 | 1.00 | 10.81 | F | C |
| ATOM | 6371 | CE1 | PHE | F | 271 | −9.112 | 67.429 | 33.228 | 1.00 | 10.70 | F | C |
| ATOM | 6372 | CE2 | PHE | F | 271 | −8.764 | 68.863 | 35.149 | 1.00 | 10.72 | F | C |
| ATOM | 6373 | CZ | PHE | F | 271 | −9.624 | 68.097 | 34.356 | 1.00 | 7.56 | F | C |
| ATOM | 6374 | C | PHE | F | 271 | −5.687 | 70.852 | 32.759 | 1.00 | 15.58 | F | C |
| ATOM | 6375 | O | PHE | F | 271 | −6.841 | 71.261 | 32.585 | 1.00 | 17.60 | F | O |
| ATOM | 6376 | N | GLN | F | 272 | −4.777 | 71.548 | 33.421 | 1.00 | 14.99 | F | N |
| ATOM | 6377 | CA | GLN | F | 272 | −5.115 | 72.855 | 33.964 | 1.00 | 15.91 | F | C |
| ATOM | 6378 | CB | GLN | F | 272 | −3.935 | 73.420 | 34.748 | 1.00 | 18.98 | F | C |
| ATOM | 6379 | CG | GLN | F | 272 | −4.195 | 73.457 | 36.238 | 1.00 | 31.09 | F | C |
| ATOM | 6380 | CD | GLN | F | 272 | −3.552 | 72.297 | 36.977 | 1.00 | 36.09 | F | C |
| ATOM | 6381 | OE1 | GLN | F | 272 | −2.441 | 72.423 | 37.495 | 1.00 | 38.01 | F | O |
| ATOM | 6382 | NE2 | GLN | F | 272 | −4.249 | 71.158 | 37.035 | 1.00 | 37.15 | F | N |
| ATOM | 6383 | C | GLN | F | 272 | −5.497 | 73.808 | 32.842 | 1.00 | 14.15 | F | C |
| ATOM | 6384 | O | GLN | F | 272 | −6.473 | 74.554 | 32.948 | 1.00 | 12.69 | F | O |
| ATOM | 6385 | N | VAL | F | 273 | −4.726 | 73.794 | 31.758 | 1.00 | 14.69 | F | N |
| ATOM | 6386 | CA | VAL | F | 273 | −5.040 | 74.675 | 30.643 | 1.00 | 11.06 | F | C |
| ATOM | 6387 | CB | VAL | F | 273 | −3.913 | 74.680 | 29.612 | 1.00 | 12.64 | F | C |
| ATOM | 6388 | CG1 | VAL | F | 273 | −4.315 | 75.542 | 28.413 | 1.00 | 10.54 | F | C |
| ATOM | 6389 | CG2 | VAL | F | 273 | −2.644 | 75.202 | 30.257 | 1.00 | 5.99 | F | C |
| ATOM | 6390 | C | VAL | F | 273 | −6.346 | 74.235 | 29.985 | 1.00 | 12.42 | F | C |
| ATOM | 6391 | O | VAL | F | 273 | −7.199 | 75.071 | 29.663 | 1.00 | 10.41 | F | O |
| ATOM | 6392 | N | HIS | F | 274 | −6.513 | 72.921 | 29.809 | 1.00 | 12.98 | F | N |
| ATOM | 6393 | CA | HIS | F | 274 | −7.732 | 72.397 | 29.201 | 1.00 | 11.90 | F | C |
| ATOM | 6394 | CB | HIS | F | 274 | −7.727 | 70.863 | 29.152 | 1.00 | 12.14 | F | C |
| ATOM | 6395 | CG | HIS | F | 274 | −9.060 | 70.264 | 28.792 | 1.00 | 15.17 | F | C |
| ATOM | 6396 | CD2 | HIS | F | 274 | −9.991 | 69.633 | 29.550 | 1.00 | 16.53 | F | C |
| ATOM | 6397 | ND1 | HIS | F | 274 | −9.584 | 70.312 | 27.513 | 1.00 | 15.23 | F | N |
| ATOM | 6398 | CE1 | HIS | F | 274 | −10.776 | 69.740 | 27.501 | 1.00 | 14.01 | F | C |
| ATOM | 6399 | NE2 | HIS | F | 274 | −11.048 | 69.320 | 28.724 | 1.00 | 12.59 | F | N |
| ATOM | 6400 | C | HIS | F | 274 | −8.959 | 72.845 | 29.966 | 1.00 | 13.96 | F | C |
| ATOM | 6401 | O | HIS | F | 274 | −9.930 | 73.320 | 29.367 | 1.00 | 13.98 | F | O |
| ATOM | 6402 | N | GLN | F | 275 | −8.924 | 72.685 | 31.291 | 1.00 | 17.39 | F | N |
| ATOM | 6403 | CA | GLN | F | 275 | −10.065 | 73.053 | 32.139 | 1.00 | 18.60 | F | C |
| ATOM | 6404 | CB | GLN | F | 275 | −9.841 | 72.597 | 33.582 | 1.00 | 21.92 | F | C |
| ATOM | 6405 | CG | GLN | F | 275 | −10.882 | 71.582 | 34.047 | 1.00 | 33.52 | F | C |
| ATOM | 6406 | CD | GLN | F | 275 | −11.087 | 71.563 | 35.570 | 1.00 | 38.80 | F | C |
| ATOM | 6407 | OE1 | GLN | F | 275 | −10.384 | 72.263 | 36.324 | 1.00 | 37.34 | F | O |
| ATOM | 6408 | NE2 | GLN | F | 275 | −12.060 | 70.757 | 36.025 | 1.00 | 34.88 | F | N |
| ATOM | 6409 | C | GLN | F | 275 | −10.405 | 74.532 | 32.137 | 1.00 | 17.76 | F | C |
| ATOM | 6410 | O | GLN | F | 275 | −11.578 | 74.899 | 32.044 | 1.00 | 17.36 | F | O |
| ATOM | 6411 | N | MET | F | 276 | −9.397 | 75.391 | 32.241 | 1.00 | 16.67 | F | N |
| ATOM | 6412 | CA | MET | F | 276 | −9.691 | 76.808 | 32.244 | 1.00 | 17.98 | F | C |
| ATOM | 6413 | CB | MET | F | 276 | −8.461 | 77.623 | 32.642 | 1.00 | 17.81 | F | C |
| ATOM | 6414 | CG | MET | F | 276 | −7.405 | 77.745 | 31.580 | 1.00 | 24.57 | F | C |
| ATOM | 6415 | SD | MET | F | 276 | −5.977 | 78.684 | 32.184 | 1.00 | 30.10 | F | S |
| ATOM | 6416 | CE | MET | F | 276 | −5.068 | 77.467 | 33.157 | 1.00 | 27.70 | F | C |
| ATOM | 6417 | C | MET | F | 276 | −10.217 | 77.250 | 30.886 | 1.00 | 17.47 | F | C |
| ATOM | 6418 | O | MET | F | 276 | −11.093 | 78.098 | 30.815 | 1.00 | 20.81 | F | O |
| ATOM | 6419 | N | LEU | F | 277 | −9.714 | 76.655 | 29.811 | 1.00 | 16.34 | F | N |
| ATOM | 6420 | CA | LEU | F | 277 | −10.160 | 77.028 | 28.474 | 1.00 | 15.58 | F | C |
| ATOM | 6421 | CB | LEU | F | 277 | −9.072 | 76.656 | 27.465 | 1.00 | 14.67 | F | C |
| ATOM | 6422 | CG | LEU | F | 277 | −8.137 | 77.710 | 26.843 | 1.00 | 20.67 | F | C |
| ATOM | 6423 | CD1 | LEU | F | 277 | −7.976 | 78.944 | 27.725 | 1.00 | 18.24 | F | C |
| ATOM | 6424 | CD2 | LEU | F | 277 | −6.801 | 77.063 | 26.600 | 1.00 | 19.59 | F | C |
| ATOM | 6425 | C | LEU | F | 277 | −11.492 | 76.396 | 28.036 | 1.00 | 15.39 | F | C |
| ATOM | 6426 | O | LEU | F | 277 | −12.307 | 77.036 | 27.376 | 1.00 | 15.65 | F | O |
| ATOM | 6427 | N | ASN | F | 278 | −11.731 | 75.149 | 28.434 | 1.00 | 15.64 | F | N |
| ATOM | 6428 | CA | ASN | F | 278 | −12.925 | 74.427 | 27.991 | 1.00 | 13.99 | F | C |
| ATOM | 6429 | CB | ASN | F | 278 | −12.479 | 73.211 | 27.167 | 1.00 | 14.26 | F | C |
| ATOM | 6430 | CG | ASN | F | 278 | −11.478 | 73.581 | 26.073 | 1.00 | 13.78 | F | C |
| ATOM | 6431 | OD1 | ASN | F | 278 | −10.334 | 73.110 | 26.056 | 1.00 | 13.15 | F | O |
| ATOM | 6432 | ND2 | ASN | F | 278 | −11.908 | 74.434 | 25.163 | 1.00 | 8.29 | F | N |
| ATOM | 6433 | C | ASN | F | 278 | −13.994 | 73.956 | 28.977 | 1.00 | 15.02 | F | C |
| ATOM | 6434 | O | ASN | F | 278 | −14.989 | 73.355 | 28.549 | 1.00 | 11.55 | F | O |
| ATOM | 6435 | N | GLU | F | 279 | −13.823 | 74.214 | 30.272 | 1.00 | 15.38 | F | N |
| ATOM | 6436 | CA | GLU | F | 279 | −14.829 | 73.753 | 31.242 | 1.00 | 17.09 | F | C |
| ATOM | 6437 | CB | GLU | F | 279 | −14.426 | 74.148 | 32.671 | 1.00 | 15.96 | F | C |
| ATOM | 6438 | CG | GLU | F | 279 | −14.371 | 75.635 | 32.898 | 1.00 | 21.09 | F | C |
| ATOM | 6439 | CD | GLU | F | 279 | −13.870 | 75.977 | 34.282 | 1.00 | 27.50 | F | C |
| ATOM | 6440 | OE1 | GLU | F | 279 | −14.153 | 75.194 | 35.216 | 1.00 | 31.27 | F | O |
| ATOM | 6441 | OE2 | GLU | F | 279 | −13.199 | 77.020 | 34.441 | 1.00 | 28.62 | F | O |
| ATOM | 6442 | C | GLU | F | 279 | −16.252 | 74.242 | 30.947 | 1.00 | 15.10 | F | C |
| ATOM | 6443 | O | GLU | F | 279 | −17.220 | 73.506 | 31.144 | 1.00 | 15.07 | F | O |
| ATOM | 6444 | N | MET | F | 280 | −16.394 | 75.474 | 30.469 | 1.00 | 15.55 | F | N |
| ATOM | 6445 | CA | MET | F | 280 | −17.727 | 75.982 | 30.168 | 1.00 | 17.25 | F | C |
| ATOM | 6446 | CB | MET | F | 280 | −17.657 | 77.484 | 29.887 | 1.00 | 20.69 | F | C |
| ATOM | 6447 | CG | MET | F | 280 | −17.566 | 78.355 | 31.162 | 1.00 | 29.34 | F | C |
| ATOM | 6448 | SD | MET | F | 280 | −18.510 | 77.761 | 32.673 | 1.00 | 38.98 | F | S |
| ATOM | 6449 | CE | MET | F | 280 | −20.172 | 78.374 | 32.317 | 1.00 | 32.79 | F | C |
| ATOM | 6450 | C | MET | F | 280 | −18.334 | 75.223 | 28.981 | 1.00 | 17.14 | F | C |
| ATOM | 6451 | O | MET | F | 280 | −19.552 | 75.063 | 28.865 | 1.00 | 16.39 | F | O |
| ATOM | 6452 | N | ASP | F | 281 | −17.463 | 74.719 | 28.122 | 1.00 | 16.36 | F | N |
| ATOM | 6453 | CA | ASP | F | 281 | −17.887 | 73.968 | 26.957 | 1.00 | 16.35 | F | C |
| ATOM | 6454 | CB | ASP | F | 281 | −16.751 | 73.952 | 25.932 | 1.00 | 21.22 | F | C |
| ATOM | 6455 | CG | ASP | F | 281 | −16.433 | 75.358 | 25.414 | 1.00 | 28.17 | F | C |
| ATOM | 6456 | OD1 | ASP | F | 281 | −15.470 | 75.999 | 25.909 | 1.00 | 30.91 | F | O |
| ATOM | 6457 | OD2 | ASP | F | 281 | −17.174 | 75.833 | 24.524 | 1.00 | 27.59 | F | O |
| ATOM | 6458 | C | ASP | F | 281 | −18.303 | 72.562 | 27.347 | 1.00 | 14.81 | F | C |
| ATOM | 6459 | O | ASP | F | 281 | −19.260 | 72.012 | 26.797 | 1.00 | 10.05 | F | O |
| ATOM | 6460 | N | GLU | F | 282 | −17.579 | 71.982 | 28.300 | 1.00 | 13.51 | F | N |
| ATOM | 6461 | CA | GLU | F | 282 | −17.905 | 70.649 | 28.779 | 1.00 | 11.26 | F | C |
| ATOM | 6462 | CB | GLU | F | 282 | −16.813 | 70.149 | 29.728 | 1.00 | 12.45 | F | C |
| ATOM | 6463 | CG | GLU | F | 282 | −15.509 | 69.809 | 29.025 | 1.00 | 8.10 | F | C |
| ATOM | 6464 | CD | GLU | F | 282 | −14.443 | 69.370 | 29.994 | 1.00 | 14.31 | F | C |
| ATOM | 6465 | OE1 | GLU | F | 282 | −14.448 | 69.858 | 31.149 | 1.00 | 11.49 | F | O |
| ATOM | 6466 | OE2 | GLU | F | 282 | −13.594 | 68.533 | 29.611 | 1.00 | 14.68 | F | O |
| ATOM | 6467 | C | GLU | F | 282 | −19.250 | 70.751 | 29.498 | 1.00 | 12.92 | F | C |
| ATOM | 6468 | O | GLU | F | 282 | −20.122 | 69.912 | 29.310 | 1.00 | 13.44 | F | O |
| ATOM | 6469 | N | LEU | F | 283 | −19.429 | 71.802 | 30.296 | 1.00 | 12.42 | F | N |
| ATOM | 6470 | CA | LEU | F | 283 | −20.680 | 72.010 | 31.021 | 1.00 | 12.28 | F | C |
| ATOM | 6471 | CB | LEU | F | 283 | −20.578 | 73.285 | 31.864 | 1.00 | 13.16 | F | C |
| ATOM | 6472 | CG | LEU | F | 283 | −21.353 | 73.459 | 33.182 | 1.00 | 17.77 | F | C |
| ATOM | 6473 | CD1 | LEU | F | 283 | −21.813 | 74.903 | 33.293 | 1.00 | 13.11 | F | C |
| ATOM | 6474 | CD2 | LEU | F | 283 | −22.534 | 72.504 | 33.265 | 1.00 | 16.06 | F | C |
| ATOM | 6475 | C | LEU | F | 283 | −21.865 | 72.133 | 30.051 | 1.00 | 13.97 | F | C |
| ATOM | 6476 | O | LEU | F | 283 | −22.967 | 71.616 | 30.309 | 1.00 | 12.19 | F | O |
| ATOM | 6477 | N | LYS | F | 284 | −21.642 | 72.837 | 28.942 | 1.00 | 14.31 | F | N |
| ATOM | 6478 | CA | LYS | F | 284 | −22.688 | 73.028 | 27.945 | 1.00 | 14.22 | F | C |
| ATOM | 6479 | CB | LYS | F | 284 | −22.153 | 73.851 | 26.772 | 1.00 | 18.51 | F | C |
| ATOM | 6480 | CG | LYS | F | 284 | −23.223 | 74.281 | 25.784 | 1.00 | 21.87 | F | C |
| ATOM | 6481 | CD | LYS | F | 284 | −22.594 | 74.757 | 24.485 | 1.00 | 28.28 | F | C |
| ATOM | 6482 | CE | LYS | F | 284 | −23.644 | 75.230 | 23.490 | 1.00 | 35.01 | F | C |
| ATOM | 6483 | NZ | LYS | F | 284 | −23.225 | 76.494 | 22.795 | 1.00 | 39.85 | F | N |
| ATOM | 6484 | C | LYS | F | 284 | −23.223 | 71.686 | 27.454 | 1.00 | 12.69 | F | C |
| ATOM | 6485 | O | LYS | F | 284 | −24.433 | 71.500 | 27.330 | 1.00 | 14.03 | F | O |
| ATOM | 6486 | N | GLU | F | 285 | −22.323 | 70.750 | 27.180 | 1.00 | 13.19 | F | N |
| ATOM | 6487 | CA | GLU | F | 285 | −22.721 | 69.417 | 26.742 | 1.00 | 11.95 | F | C |
| ATOM | 6488 | CB | GLU | F | 285 | −21.494 | 68.510 | 26.582 | 1.00 | 10.19 | F | C |
| ATOM | 6489 | CG | GLU | F | 285 | −20.653 | 68.762 | 25.350 | 1.00 | 12.46 | F | C |
| ATOM | 6490 | CD | GLU | F | 285 | −19.678 | 67.625 | 25.069 | 1.00 | 16.50 | F | C |
| ATOM | 6491 | OE1 | GLU | F | 285 | −20.139 | 66.501 | 24.730 | 1.00 | 16.39 | F | O |
| ATOM | 6492 | OE2 | GLU | F | 285 | −18.446 | 67.855 | 25.188 | 1.00 | 16.78 | F | O |
| ATOM | 6493 | C | GLU | F | 285 | −23.652 | 68.786 | 27.778 | 1.00 | 13.60 | F | C |
| ATOM | 6494 | O | GLU | F | 285 | −24.680 | 68.189 | 27.433 | 1.00 | 12.67 | F | O |
| ATOM | 6495 | N | LEU | F | 286 | −23.287 | 68.905 | 29.056 | 1.00 | 15.58 | F | N |
| ATOM | 6496 | CA | LEU | F | 286 | −24.100 | 68.313 | 30.121 | 1.00 | 15.85 | F | C |
| ATOM | 6497 | CB | LEU | F | 286 | −23.382 | 68.384 | 31.480 | 1.00 | 16.24 | F | C |
| ATOM | 6498 | CG | LEU | F | 286 | −21.971 | 67.811 | 31.739 | 1.00 | 19.35 | F | C |
| ATOM | 6499 | CD1 | LEU | F | 286 | −22.015 | 67.005 | 33.024 | 1.00 | 15.78 | F | C |
| ATOM | 6500 | CD2 | LEU | F | 286 | −21.445 | 66.972 | 30.577 | 1.00 | 10.43 | F | C |
| ATOM | 6501 | C | LEU | F | 286 | −25.445 | 69.007 | 30.220 | 1.00 | 14.56 | F | C |
| ATOM | 6502 | O | LEU | F | 286 | −26.474 | 68.351 | 30.316 | 1.00 | 14.68 | F | O |
| ATOM | 6503 | N | LYS | F | 287 | −25.444 | 70.335 | 30.196 | 1.00 | 17.05 | F | N |
| ATOM | 6504 | CA | LYS | F | 287 | −26.700 | 71.065 | 30.286 | 1.00 | 19.25 | F | C |
| ATOM | 6505 | CB | LYS | F | 287 | −26.456 | 72.567 | 30.259 | 1.00 | 19.80 | F | C |
| ATOM | 6506 | CG | LYS | F | 287 | −25.927 | 73.124 | 31.558 | 1.00 | 20.17 | F | C |
| ATOM | 6507 | CD | LYS | F | 287 | −25.175 | 74.408 | 31.300 | 1.00 | 22.85 | F | C |
| ATOM | 6508 | CE | LYS | F | 287 | −25.708 | 75.564 | 32.119 | 1.00 | 27.58 | F | C |
| ATOM | 6509 | NZ | LYS | F | 287 | −24.663 | 76.634 | 32.259 | 1.00 | 29.31 | F | N |
| ATOM | 6510 | C | LYS | F | 287 | −27.600 | 70.685 | 29.125 | 1.00 | 21.47 | F | C |
| ATOM | 6511 | O | LYS | F | 287 | −28.818 | 70.572 | 29.283 | 1.00 | 22.05 | F | O |
| ATOM | 6512 | N | ASN | F | 288 | −26.997 | 70.471 | 27.960 | 1.00 | 21.97 | F | N |
| ATOM | 6513 | CA | ASN | F | 288 | −27.770 | 70.118 | 26.770 | 1.00 | 23.40 | F | C |
| ATOM | 6514 | CB | ASN | F | 288 | −27.049 | 70.598 | 25.503 | 1.00 | 24.09 | F | C |
| ATOM | 6515 | CG | ASN | F | 288 | −27.102 | 72.118 | 25.342 | 1.00 | 25.60 | F | C |
| ATOM | 6516 | OD1 | ASN | F | 288 | −28.124 | 72.748 | 25.604 | 1.00 | 26.55 | F | O |
| ATOM | 6517 | ND2 | ASN | F | 288 | −25.995 | 72.708 | 24.912 | 1.00 | 29.88 | F | N |
| ATOM | 6518 | C | ASN | F | 288 | −28.079 | 68.630 | 26.658 | 1.00 | 23.75 | F | C |
| ATOM | 6519 | O | ASN | F | 288 | −28.629 | 68.178 | 25.665 | 1.00 | 24.40 | F | O |
| ATOM | 6520 | N | ASN | F | 289 | −27.712 | 67.872 | 27.678 | 1.00 | 24.06 | F | N |
| ATOM | 6521 | CA | ASN | F | 289 | −27.975 | 66.435 | 27.713 | 1.00 | 23.81 | F | C |
| ATOM | 6522 | CB | ASN | F | 289 | −26.757 | 65.712 | 28.282 | 1.00 | 18.36 | F | C |
| ATOM | 6523 | CG | ASN | F | 289 | −26.933 | 64.230 | 28.304 | 1.00 | 15.52 | F | C |
| ATOM | 6524 | OD1 | ASN | F | 289 | −27.505 | 63.658 | 27.389 | 1.00 | 14.57 | F | O |
| ATOM | 6525 | ND2 | ASN | F | 289 | −26.451 | 63.590 | 29.357 | 1.00 | 16.82 | F | N |
| ATOM | 6526 | C | ASN | F | 289 | −29.177 | 66.259 | 28.647 | 1.00 | 25.41 | F | C |
| ATOM | 6527 | O | ASN | F | 289 | −29.016 | 66.151 | 29.851 | 1.00 | 29.71 | F | O |
| ATOM | 6528 | N | PRO | F | 290 | −30.397 | 66.231 | 28.104 | 1.00 | 26.88 | F | N |
| ATOM | 6529 | CD | PRO | F | 290 | −30.729 | 66.318 | 26.673 | 1.00 | 27.28 | F | C |
| ATOM | 6530 | CA | PRO | F | 290 | −31.602 | 66.084 | 28.930 | 1.00 | 27.78 | F | C |
| ATOM | 6531 | CB | PRO | F | 290 | −32.720 | 66.455 | 27.973 | 1.00 | 30.17 | F | C |
| ATOM | 6532 | CG | PRO | F | 290 | −32.193 | 65.999 | 26.649 | 1.00 | 26.46 | F | C |
| ATOM | 6533 | C | PRO | F | 290 | −31.833 | 64.715 | 29.556 | 1.00 | 28.29 | F | C |
| ATOM | 6534 | O | PRO | F | 290 | −32.610 | 64.568 | 30.508 | 1.00 | 28.29 | F | O |
| ATOM | 6535 | N | HIS | F | 291 | −31.157 | 63.713 | 29.025 | 1.00 | 28.72 | F | N |
| ATOM | 6536 | CA | HIS | F | 291 | −31.313 | 62.362 | 29.537 | 1.00 | 35.62 | F | C |
| ATOM | 6537 | CB | HIS | F | 291 | −30.721 | 61.357 | 28.549 | 1.00 | 38.25 | F | C |
| ATOM | 6538 | CG | HIS | F | 291 | −31.330 | 61.441 | 27.189 | 1.00 | 47.48 | F | C |
| ATOM | 6539 | CD2 | HIS | F | 291 | −32.396 | 60.804 | 26.651 | 1.00 | 47.35 | F | C |
| ATOM | 6540 | ND1 | HIS | F | 291 | −30.883 | 62.326 | 26.230 | 1.00 | 50.98 | F | N |
| ATOM | 6541 | CE1 | HIS | F | 291 | −31.652 | 62.232 | 25.159 | 1.00 | 51.89 | F | C |
| ATOM | 6542 | NE2 | HIS | F | 291 | −32.577 | 61.316 | 25.389 | 1.00 | 49.64 | F | N |
| ATOM | 6543 | C | HIS | F | 291 | −30.677 | 62.128 | 30.901 | 1.00 | 36.08 | F | C |
| ATOM | 6544 | O | HIS | F | 291 | −30.941 | 61.110 | 31.544 | 1.00 | 38.68 | F | O |
| ATOM | 6545 | N | ARG | F | 292 | −29.866 | 63.061 | 31.375 | 1.00 | 30.23 | F | N |
| ATOM | 6546 | CA | ARG | F | 292 | −29.208 | 62.773 | 32.615 | 1.00 | 24.50 | F | C |
| ATOM | 6547 | CB | ARG | F | 292 | −28.141 | 61.712 | 32.333 | 1.00 | 24.41 | F | C |
| ATOM | 6548 | CG | ARG | F | 292 | −28.344 | 60.442 | 33.107 | 1.00 | 28.78 | F | C |
| ATOM | 6549 | CD | ARG | F | 292 | −27.768 | 59.282 | 32.399 | 1.00 | 25.68 | F | C |
| ATOM | 6550 | NE | ARG | F | 292 | −28.766 | 58.575 | 31.608 | 1.00 | 23.10 | F | N |
| ATOM | 6551 | CZ | ARG | F | 292 | −29.646 | 57.705 | 32.085 | 1.00 | 24.98 | F | C |
| ATOM | 6552 | NH1 | ARG | F | 292 | −29.695 | 57.395 | 33.377 | 1.00 | 28.53 | F | N |
| ATOM | 6553 | NH2 | ARG | F | 292 | −30.450 | 57.089 | 31.247 | 1.00 | 27.36 | F | N |
| ATOM | 6554 | C | ARG | F | 292 | −28.551 | 63.917 | 33.332 | 1.00 | 23.06 | F | C |
| ATOM | 6555 | O | ARG | F | 292 | −28.315 | 64.983 | 32.758 | 1.00 | 20.29 | F | O |
| ATOM | 6556 | N | ASP | F | 293 | −28.294 | 63.669 | 34.615 | 1.00 | 17.75 | F | N |
| ATOM | 6557 | CA | ASP | F | 293 | −27.533 | 64.576 | 35.451 | 1.00 | 19.40 | F | C |
| ATOM | 6558 | CB | ASP | F | 293 | −28.395 | 65.649 | 36.153 | 1.00 | 16.72 | F | C |
| ATOM | 6559 | CG | ASP | F | 293 | −29.475 | 65.086 | 37.047 | 1.00 | 19.49 | F | C |
| ATOM | 6560 | OD1 | ASP | F | 293 | −30.454 | 65.841 | 37.236 | 1.00 | 17.58 | F | O |
| ATOM | 6561 | OD2 | ASP | F | 293 | −29.367 | 63.943 | 37.563 | 1.00 | 16.77 | F | O |
| ATOM | 6562 | C | ASP | F | 293 | −26.797 | 63.647 | 36.412 | 1.00 | 19.39 | F | C |
| ATOM | 6563 | O | ASP | F | 293 | −26.915 | 62.422 | 36.280 | 1.00 | 17.33 | F | O |
| ATOM | 6564 | N | PHE | F | 294 | −26.015 | 64.198 | 37.335 | 1.00 | 18.21 | F | N |
| ATOM | 6565 | CA | PHE | F | 294 | −25.271 | 63.349 | 38.256 | 1.00 | 18.78 | F | C |
| ATOM | 6566 | CB | PHE | F | 294 | −24.504 | 64.191 | 39.292 | 1.00 | 17.15 | F | C |
| ATOM | 6567 | CG | PHE | F | 294 | −23.691 | 63.364 | 40.259 | 1.00 | 19.59 | F | C |
| ATOM | 6568 | CD1 | PHE | F | 294 | −22.464 | 62.813 | 39.878 | 1.00 | 16.76 | F | C |
| ATOM | 6569 | CD2 | PHE | F | 294 | −24.159 | 63.115 | 41.546 | 1.00 | 19.60 | F | C |
| ATOM | 6570 | CE1 | PHE | F | 294 | −21.713 | 62.024 | 40.765 | 1.00 | 16.56 | F | C |
| ATOM | 6571 | CE2 | PHE | F | 294 | −23.409 | 62.324 | 42.443 | 1.00 | 19.77 | F | C |
| ATOM | 6572 | CZ | PHE | F | 294 | −22.188 | 61.784 | 42.044 | 1.00 | 15.51 | F | C |
| ATOM | 6573 | C | PHE | F | 294 | −26.156 | 62.354 | 38.986 | 1.00 | 17.23 | F | C |
| ATOM | 6574 | O | PHE | F | 294 | −25.777 | 61.206 | 39.188 | 1.00 | 18.60 | F | O |
| ATOM | 6575 | N | TYR | F | 295 | −27.359 | 62.778 | 39.335 | 1.00 | 16.33 | F | N |
| ATOM | 6576 | CA | TYR | F | 295 | −28.233 | 61.931 | 40.104 | 1.00 | 14.91 | F | C |
| ATOM | 6577 | CB | TYR | F | 295 | −29.305 | 62.797 | 40.751 | 1.00 | 14.75 | F | C |
| ATOM | 6578 | CG | TYR | F | 295 | −28.677 | 63.804 | 41.693 | 1.00 | 16.22 | F | C |
| ATOM | 6579 | CD1 | TYR | F | 295 | −28.162 | 63.405 | 42.924 | 1.00 | 17.61 | F | C |
| ATOM | 6580 | CE1 | TYR | F | 295 | −27.485 | 64.305 | 43.752 | 1.00 | 19.11 | F | C |
| ATOM | 6581 | CD2 | TYR | F | 295 | −28.504 | 65.130 | 41.314 | 1.00 | 15.65 | F | C |
| ATOM | 6582 | CE2 | TYR | F | 295 | −27.832 | 66.033 | 42.128 | 1.00 | 17.63 | F | C |
| ATOM | 6583 | CZ | TYR | F | 295 | −27.325 | 65.619 | 43.348 | 1.00 | 20.03 | F | C |
| ATOM | 6584 | OH | TYR | F | 295 | −26.693 | 66.528 | 44.182 | 1.00 | 22.11 | F | O |
| ATOM | 6585 | C | TYR | F | 295 | −28.813 | 60.683 | 39.466 | 1.00 | 19.03 | F | C |
| ATOM | 6586 | O | TYR | F | 295 | −29.294 | 59.799 | 40.180 | 1.00 | 20.77 | F | O |
| ATOM | 6587 | N | ASN | F | 296 | −28.787 | 60.566 | 38.145 | 1.00 | 17.63 | F | N |
| ATOM | 6588 | CA | ASN | F | 296 | −29.276 | 59.317 | 37.578 | 1.00 | 17.01 | F | C |
| ATOM | 6589 | CB | ASN | F | 296 | −30.604 | 59.485 | 36.827 | 1.00 | 18.47 | F | C |
| ATOM | 6590 | CG | ASN | F | 296 | −30.550 | 60.500 | 35.723 | 1.00 | 18.30 | F | C |
| ATOM | 6591 | OD1 | ASN | F | 296 | −31.489 | 60.588 | 34.956 | 1.00 | 20.45 | F | O |
| ATOM | 6592 | ND2 | ASN | F | 296 | −29.473 | 61.274 | 35.634 | 1.00 | 17.79 | F | N |
| ATOM | 6593 | C | ASN | F | 296 | −28.248 | 58.590 | 36.725 | 1.00 | 16.83 | F | C |
| ATOM | 6594 | O | ASN | F | 296 | −28.596 | 57.885 | 35.773 | 1.00 | 15.50 | F | O |
| ATOM | 6595 | N | CYS | F | 297 | −26.980 | 58.788 | 37.098 | 1.00 | 16.45 | F | N |
| ATOM | 6596 | CA | CYS | F | 297 | −25.816 | 58.136 | 36.502 | 1.00 | 16.19 | F | C |
| ATOM | 6597 | CB | CYS | F | 297 | −24.586 | 59.058 | 36.490 | 1.00 | 19.90 | F | C |
| ATOM | 6598 | SG | CYS | F | 297 | −24.620 | 60.351 | 35.258 | 1.00 | 28.49 | F | S |
| ATOM | 6599 | C | CYS | F | 297 | −25.538 | 57.055 | 37.530 | 1.00 | 14.52 | F | C |
| ATOM | 6600 | O | CYS | F | 297 | −25.776 | 57.268 | 38.714 | 1.00 | 14.36 | F | O |
| ATOM | 6601 | N | ARG | F | 298 | −25.035 | 55.908 | 37.096 | 1.00 | 14.81 | F | N |
| ATOM | 6602 | CA | ARG | F | 298 | −24.709 | 54.847 | 38.029 | 1.00 | 15.68 | F | C |
| ATOM | 6603 | CB | ARG | F | 298 | −24.681 | 53.501 | 37.308 | 1.00 | 14.35 | F | C |
| ATOM | 6604 | CG | ARG | F | 298 | −25.999 | 52.797 | 37.298 | 1.00 | 16.28 | F | C |
| ATOM | 6605 | CD | ARG | F | 298 | −26.972 | 53.493 | 36.365 | 1.00 | 15.73 | F | C |
| ATOM | 6606 | NE | ARG | F | 298 | −28.263 | 52.813 | 36.362 | 1.00 | 18.24 | F | N |
| ATOM | 6607 | CZ | ARG | F | 298 | −29.268 | 53.114 | 35.550 | 1.00 | 18.83 | F | C |
| ATOM | 6608 | NH1 | ARG | F | 298 | −29.138 | 54.094 | 34.664 | 1.00 | 16.20 | F | N |
| ATOM | 6609 | NH2 | ARG | F | 298 | −30.402 | 52.437 | 35.632 | 1.00 | 20.03 | F | N |
| ATOM | 6610 | C | ARG | F | 298 | −23.326 | 55.125 | 38.640 | 1.00 | 18.76 | F | C |
| ATOM | 6611 | O | ARG | F | 298 | −22.417 | 55.623 | 37.954 | 1.00 | 17.33 | F | O |
| ATOM | 6612 | N | LYS | F | 299 | −23.185 | 54.819 | 39.930 | 1.00 | 17.44 | F | N |
| ATOM | 6613 | CA | LYS | F | 299 | −21.927 | 54.989 | 40.660 | 1.00 | 14.58 | F | C |
| ATOM | 6614 | CB | LYS | F | 299 | −22.045 | 56.096 | 41.704 | 1.00 | 13.88 | F | C |
| ATOM | 6615 | CG | LYS | F | 299 | −21.766 | 57.478 | 41.188 | 1.00 | 15.16 | F | C |
| ATOM | 6616 | CD | LYS | F | 299 | −23.006 | 58.043 | 40.553 | 1.00 | 16.56 | F | C |
| ATOM | 6617 | CE | LYS | F | 299 | −23.913 | 58.695 | 41.558 | 1.00 | 14.33 | F | C |
| ATOM | 6618 | NZ | LYS | F | 299 | −25.266 | 58.865 | 40.968 | 1.00 | 10.03 | F | N |
| ATOM | 6619 | C | LYS | F | 299 | −21.717 | 53.673 | 41.376 | 1.00 | 12.00 | F | C |
| ATOM | 6620 | O | LYS | F | 299 | −22.658 | 53.131 | 41.942 | 1.00 | 11.19 | F | O |
| ATOM | 6621 | N | VAL | F | 300 | −20.500 | 53.150 | 41.349 | 1.00 | 11.70 | F | N |
| ATOM | 6622 | CA | VAL | F | 300 | −20.228 | 51.888 | 42.019 | 1.00 | 10.14 | F | C |
| ATOM | 6623 | CB | VAL | F | 300 | −19.734 | 50.842 | 41.011 | 1.00 | 9.31 | F | C |
| ATOM | 6624 | CG1 | VAL | F | 300 | −19.564 | 49.489 | 41.693 | 1.00 | 8.76 | F | C |
| ATOM | 6625 | CG2 | VAL | F | 300 | −20.727 | 50.733 | 39.865 | 1.00 | 7.62 | F | C |
| ATOM | 6626 | C | VAL | F | 300 | −19.189 | 52.060 | 43.133 | 1.00 | 13.65 | F | C |
| ATOM | 6627 | O | VAL | F | 300 | −18.194 | 52.774 | 42.960 | 1.00 | 14.84 | F | O |
| ATOM | 6628 | N | ASP | F | 301 | −19.441 | 51.438 | 44.285 | 1.00 | 14.40 | F | N |
| ATOM | 6629 | CA | ASP | F | 301 | −18.497 | 51.512 | 45.405 | 1.00 | 13.05 | F | C |
| ATOM | 6630 | CB | ASP | F | 301 | −19.210 | 51.289 | 46.749 | 1.00 | 13.40 | F | C |
| ATOM | 6631 | CG | ASP | F | 301 | −18.391 | 51.794 | 47.945 | 1.00 | 13.75 | F | C |
| ATOM | 6632 | OD1 | ASP | F | 301 | −18.995 | 52.038 | 49.008 | 1.00 | 17.20 | F | O |
| ATOM | 6633 | OD2 | ASP | F | 301 | −17.155 | 51.939 | 47.836 | 1.00 | 10.04 | F | O |
| ATOM | 6634 | C | ASP | F | 301 | −17.572 | 50.367 | 45.091 | 1.00 | 11.00 | F | C |
| ATOM | 6635 | O | ASP | F | 301 | −17.878 | 49.204 | 45.359 | 1.00 | 10.97 | F | O |
| ATOM | 6636 | N | THR | F | 302 | −16.441 | 50.713 | 44.498 | 1.00 | 11.14 | F | N |
| ATOM | 6637 | CA | THR | F | 302 | −15.466 | 49.732 | 44.057 | 1.00 | 12.50 | F | C |
| ATOM | 6638 | CB | THR | F | 302 | −14.630 | 50.339 | 42.914 | 1.00 | 13.06 | F | C |
| ATOM | 6639 | OG1 | THR | F | 302 | −14.183 | 51.640 | 43.309 | 1.00 | 15.18 | F | O |
| ATOM | 6640 | CG2 | THR | F | 302 | −15.489 | 50.485 | 41.640 | 1.00 | 6.71 | F | C |
| ATOM | 6641 | C | THR | F | 302 | −14.541 | 49.162 | 45.127 | 1.00 | 13.44 | F | C |
| ATOM | 6642 | O | THR | F | 302 | −13.774 | 48.251 | 44.858 | 1.00 | 15.67 | F | O |
| ATOM | 6643 | N | HIS | F | 303 | −14.603 | 49.697 | 46.336 | 1.00 | 13.43 | F | N |
| ATOM | 6644 | CA | HIS | F | 303 | −13.770 | 49.199 | 47.418 | 1.00 | 13.26 | F | C |
| ATOM | 6645 | CB | HIS | F | 303 | −12.441 | 49.949 | 47.439 | 1.00 | 16.48 | F | C |
| ATOM | 6646 | CG | HIS | F | 303 | −11.737 | 49.900 | 48.763 | 1.00 | 19.97 | F | C |
| ATOM | 6647 | CD2 | HIS | F | 303 | −11.478 | 48.866 | 49.597 | 1.00 | 16.16 | F | C |
| ATOM | 6648 | ND1 | HIS | F | 303 | −11.193 | 51.020 | 49.361 | 1.00 | 18.87 | F | N |
| ATOM | 6649 | CE1 | HIS | F | 303 | −10.629 | 50.679 | 50.505 | 1.00 | 16.69 | F | C |
| ATOM | 6650 | NE2 | HIS | F | 303 | −10.789 | 49.377 | 50.672 | 1.00 | 21.39 | F | N |
| ATOM | 6651 | C | HIS | F | 303 | −14.530 | 49.399 | 48.727 | 1.00 | 12.82 | F | C |
| ATOM | 6652 | O | HIS | F | 303 | −14.581 | 50.504 | 49.256 | 1.00 | 10.51 | F | O |
| ATOM | 6653 | N | ILE | F | 304 | −15.127 | 48.315 | 49.218 | 1.00 | 12.97 | F | N |
| ATOM | 6654 | CA | ILE | F | 304 | −15.908 | 48.323 | 50.440 | 1.00 | 14.58 | F | C |
| ATOM | 6655 | CB | ILE | F | 304 | −17.388 | 48.785 | 50.151 | 1.00 | 14.22 | F | C |
| ATOM | 6656 | CG2 | ILE | F | 304 | −17.980 | 47.990 | 49.006 | 1.00 | 12.66 | F | C |
| ATOM | 6657 | CG1 | ILE | F | 304 | −18.240 | 48.631 | 51.403 | 1.00 | 12.26 | F | C |
| ATOM | 6658 | CD1 | ILE | F | 304 | −19.573 | 49.323 | 51.310 | 1.00 | 16.52 | F | C |
| ATOM | 6659 | C | ILE | F | 304 | −15.904 | 46.917 | 51.068 | 1.00 | 16.48 | F | C |
| ATOM | 6660 | O | ILE | F | 304 | −16.031 | 45.911 | 50.364 | 1.00 | 14.70 | F | O |
| ATOM | 6661 | N | HIS | F | 305 | −15.752 | 46.860 | 52.391 | 1.00 | 16.13 | F | N |
| ATOM | 6662 | CA | HIS | F | 305 | −15.723 | 45.589 | 53.131 | 1.00 | 11.97 | F | C |
| ATOM | 6663 | CB | HIS | F | 305 | −14.670 | 45.672 | 54.243 | 1.00 | 11.31 | F | C |
| ATOM | 6664 | CG | HIS | F | 305 | −13.313 | 46.081 | 53.751 | 1.00 | 10.77 | F | C |
| ATOM | 6665 | CD2 | HIS | F | 305 | −12.783 | 47.306 | 53.508 | 1.00 | 13.47 | F | C |
| ATOM | 6666 | ND1 | HIS | F | 305 | −12.338 | 45.169 | 53.398 | 1.00 | 13.00 | F | N |
| ATOM | 6667 | CE1 | HIS | F | 305 | −11.269 | 45.812 | 52.962 | 1.00 | 12.41 | F | C |
| ATOM | 6668 | NE2 | HIS | F | 305 | −11.512 | 47.111 | 53.017 | 1.00 | 10.65 | F | N |
| ATOM | 6669 | C | HIS | F | 305 | −17.108 | 45.292 | 53.700 | 1.00 | 11.53 | F | C |
| ATOM | 6670 | O | HIS | F | 305 | −17.723 | 46.156 | 54.306 | 1.00 | 12.90 | F | O |
| ATOM | 6671 | N | ALA | F | 306 | −17.604 | 44.074 | 53.490 | 1.00 | 12.05 | F | N |
| ATOM | 6672 | CA | ALA | F | 306 | −18.941 | 43.689 | 53.953 | 1.00 | 13.34 | F | C |
| ATOM | 6673 | CB | ALA | F | 306 | −19.228 | 42.237 | 53.565 | 1.00 | 10.82 | F | C |
| ATOM | 6674 | C | ALA | F | 306 | −19.156 | 43.871 | 55.459 | 1.00 | 13.80 | F | C |
| ATOM | 6675 | O | ALA | F | 306 | −20.215 | 44.323 | 55.895 | 1.00 | 14.17 | F | O |
| ATOM | 6676 | N | ALA | F | 307 | −18.146 | 43.515 | 56.243 | 1.00 | 14.08 | F | N |
| ATOM | 6677 | CA | ALA | F | 307 | −18.221 | 43.626 | 57.690 | 1.00 | 14.53 | F | C |
| ATOM | 6678 | CB | ALA | F | 307 | −16.963 | 43.039 | 58.306 | 1.00 | 10.10 | F | C |
| ATOM | 6679 | C | ALA | F | 307 | −18.429 | 45.057 | 58.180 | 1.00 | 15.49 | F | C |
| ATOM | 6680 | O | ALA | F | 307 | −18.663 | 45.266 | 59.363 | 1.00 | 19.70 | F | O |
| ATOM | 6681 | N | ALA | F | 308 | −18.353 | 46.038 | 57.280 | 1.00 | 15.94 | F | N |
| ATOM | 6682 | CA | ALA | F | 308 | −18.526 | 47.435 | 57.663 | 1.00 | 14.19 | F | C |
| ATOM | 6683 | CB | ALA | F | 308 | −17.173 | 48.105 | 57.785 | 1.00 | 17.42 | F | C |
| ATOM | 6684 | C | ALA | F | 308 | −19.358 | 48.212 | 56.678 | 1.00 | 15.80 | F | C |
| ATOM | 6685 | O | ALA | F | 308 | −19.323 | 49.450 | 56.675 | 1.00 | 15.15 | F | O |
| ATOM | 6686 | N | CYS | F | 309 | −20.111 | 47.504 | 55.847 | 1.00 | 15.59 | F | N |
| ATOM | 6687 | CA | CYS | F | 309 | −20.908 | 48.177 | 54.826 | 1.00 | 17.37 | F | C |
| ATOM | 6688 | CB | CYS | F | 309 | −21.344 | 47.173 | 53.755 | 1.00 | 16.61 | F | C |
| ATOM | 6689 | SG | CYS | F | 309 | −22.574 | 45.951 | 54.303 | 1.00 | 18.41 | F | S |
| ATOM | 6690 | C | CYS | F | 309 | −22.118 | 48.925 | 55.357 | 1.00 | 18.53 | F | C |
| ATOM | 6691 | O | CYS | F | 309 | −22.749 | 49.689 | 54.619 | 1.00 | 19.56 | F | O |
| ATOM | 6692 | N | MET | F | 310 | −22.443 | 48.721 | 56.633 | 1.00 | 18.82 | F | N |
| ATOM | 6693 | CA | MET | F | 310 | −23.600 | 49.393 | 57.236 | 1.00 | 18.66 | F | C |
| ATOM | 6694 | CB | MET | F | 310 | −24.418 | 48.393 | 58.075 | 1.00 | 17.18 | F | C |
| ATOM | 6695 | CG | MET | F | 310 | −23.792 | 48.043 | 59.432 | 1.00 | 12.88 | F | C |
| ATOM | 6696 | SD | MET | F | 310 | −22.163 | 47.236 | 59.356 | 1.00 | 17.80 | F | S |
| ATOM | 6697 | CE | MET | F | 310 | −22.550 | 45.688 | 58.449 | 1.00 | 15.09 | F | C |
| ATOM | 6698 | C | MET | F | 310 | −23.215 | 50.601 | 58.104 | 1.00 | 18.67 | F | C |
| ATOM | 6699 | O | MET | F | 310 | −22.123 | 50.657 | 58.662 | 1.00 | 18.17 | F | O |
| ATOM | 6700 | N | ASN | F | 311 | −24.126 | 51.565 | 58.199 | 1.00 | 18.90 | F | N |
| ATOM | 6701 | CA | ASN | F | 311 | −23.911 | 52.762 | 59.012 | 1.00 | 21.38 | F | C |
| ATOM | 6702 | CB | ASN | F | 311 | −24.983 | 53.817 | 58.712 | 1.00 | 22.42 | F | C |
| ATOM | 6703 | CG | ASN | F | 311 | −24.747 | 55.122 | 59.468 | 1.00 | 25.98 | F | C |
| ATOM | 6704 | OD1 | ASN | F | 311 | −23.721 | 55.774 | 59.295 | 1.00 | 29.75 | F | O |
| ATOM | 6705 | ND2 | ASN | F | 311 | −25.700 | 55.503 | 60.307 | 1.00 | 27.83 | F | N |
| ATOM | 6706 | C | ASN | F | 311 | −23.992 | 52.383 | 60.495 | 1.00 | 21.93 | F | C |
| ATOM | 6707 | O | ASN | F | 311 | −24.673 | 51.414 | 60.867 | 1.00 | 18.75 | F | O |
| ATOM | 6708 | N | GLN | F | 312 | −23.299 | 53.139 | 61.340 | 1.00 | 19.89 | F | N |
| ATOM | 6709 | CA | GLN | F | 312 | −23.338 | 52.853 | 62.765 | 1.00 | 19.90 | F | C |
| ATOM | 6710 | CB | GLN | F | 312 | −22.425 | 53.818 | 63.505 | 1.00 | 20.18 | F | C |
| ATOM | 6711 | CG | GLN | F | 312 | −22.842 | 55.250 | 63.375 | 1.00 | 18.39 | F | C |
| ATOM | 6712 | CD | GLN | F | 312 | −21.883 | 56.169 | 64.080 | 1.00 | 19.89 | F | C |
| ATOM | 6713 | OE1 | GLN | F | 312 | −21.104 | 55.726 | 64.919 | 1.00 | 20.15 | F | O |
| ATOM | 6714 | NE2 | GLN | F | 312 | −21.918 | 57.458 | 63.737 | 1.00 | 20.99 | F | N |
| ATOM | 6715 | C | GLN | F | 312 | −24.780 | 52.950 | 63.311 | 1.00 | 19.66 | F | C |
| ATOM | 6716 | O | GLN | F | 312 | −25.168 | 52.169 | 64.169 | 1.00 | 19.42 | F | O |
| ATOM | 6717 | N | LYS | F | 313 | −25.575 | 53.892 | 62.804 | 1.00 | 17.31 | F | N |
| ATOM | 6718 | CA | LYS | F | 313 | −26.962 | 54.045 | 63.252 | 1.00 | 18.29 | F | C |
| ATOM | 6719 | CB | LYS | F | 313 | −27.578 | 55.317 | 62.678 | 1.00 | 20.95 | F | C |
| ATOM | 6720 | CG | LYS | F | 313 | −26.972 | 56.596 | 63.220 | 1.00 | 26.15 | F | C |
| ATOM | 6721 | CD | LYS | F | 313 | −27.913 | 57.760 | 63.007 | 1.00 | 28.65 | F | C |
| ATOM | 6722 | CE | LYS | F | 313 | −27.826 | 58.267 | 61.586 | 1.00 | 31.96 | F | C |
| ATOM | 6723 | NZ | LYS | F | 313 | −28.829 | 59.342 | 61.361 | 1.00 | 34.63 | F | N |
| ATOM | 6724 | C | LYS | F | 313 | −27.816 | 52.869 | 62.817 | 1.00 | 18.08 | F | C |
| ATOM | 6725 | O | LYS | F | 313 | −28.823 | 52.552 | 63.441 | 1.00 | 16.75 | F | O |
| ATOM | 6726 | N | HIS | F | 314 | −27.408 | 52.244 | 61.719 | 1.00 | 19.07 | F | N |
| ATOM | 6727 | CA | HIS | F | 314 | −28.096 | 51.089 | 61.167 | 1.00 | 17.50 | F | C |
| ATOM | 6728 | CB | HIS | F | 314 | −27.605 | 50.869 | 59.735 | 1.00 | 20.04 | F | C |
| ATOM | 6729 | CG | HIS | F | 314 | −28.247 | 49.716 | 59.034 | 1.00 | 21.78 | F | C |
| ATOM | 6730 | CD2 | HIS | F | 314 | −27.981 | 49.152 | 57.833 | 1.00 | 21.03 | F | C |
| ATOM | 6731 | ND1 | HIS | F | 314 | −29.264 | 48.972 | 59.592 | 1.00 | 23.48 | F | N |
| ATOM | 6732 | CE1 | HIS | F | 314 | −29.595 | 47.994 | 58.767 | 1.00 | 22.73 | F | C |
| ATOM | 6733 | NE2 | HIS | F | 314 | −28.831 | 48.081 | 57.692 | 1.00 | 25.51 | F | N |
| ATOM | 6734 | C | HIS | F | 314 | −27.766 | 49.889 | 62.065 | 1.00 | 17.09 | F | C |
| ATOM | 6735 | O | HIS | F | 314 | −28.657 | 49.141 | 62.469 | 1.00 | 17.01 | F | O |
| ATOM | 6736 | N | LEU | F | 315 | −26.489 | 49.711 | 62.384 | 1.00 | 13.43 | F | N |
| ATOM | 6737 | CA | LEU | F | 315 | −26.098 | 48.622 | 63.265 | 1.00 | 15.27 | F | C |
| ATOM | 6738 | CB | LEU | F | 315 | −24.579 | 48.613 | 63.455 | 1.00 | 14.55 | F | C |
| ATOM | 6739 | CG | LEU | F | 315 | −24.064 | 47.630 | 64.513 | 1.00 | 15.22 | F | C |
| ATOM | 6740 | CD1 | LEU | F | 315 | −24.496 | 46.214 | 64.136 | 1.00 | 14.48 | F | C |
| ATOM | 6741 | CD2 | LEU | F | 315 | −22.533 | 47.722 | 64.643 | 1.00 | 12.50 | F | C |
| ATOM | 6742 | C | LEU | F | 315 | −26.800 | 48.792 | 64.628 | 1.00 | 16.50 | F | C |
| ATOM | 6743 | O | LEU | F | 315 | −27.345 | 47.835 | 65.168 | 1.00 | 19.03 | F | O |
| ATOM | 6744 | N | LEU | F | 316 | −26.794 | 50.008 | 65.174 | 1.00 | 15.01 | F | N |
| ATOM | 6745 | CA | LEU | F | 316 | −27.438 | 50.284 | 66.454 | 1.00 | 15.40 | F | C |
| ATOM | 6746 | CB | LEU | F | 316 | −27.323 | 51.772 | 66.792 | 1.00 | 15.54 | F | C |
| ATOM | 6747 | CG | LEU | F | 316 | −27.893 | 52.222 | 68.145 | 1.00 | 17.00 | F | C |
| ATOM | 6748 | CD1 | LEU | F | 316 | −27.113 | 51.548 | 69.288 | 1.00 | 12.61 | F | C |
| ATOM | 6749 | CD2 | LEU | F | 316 | −27.815 | 53.734 | 68.260 | 1.00 | 15.66 | F | C |
| ATOM | 6750 | C | LEU | F | 316 | −28.914 | 49.882 | 66.438 | 1.00 | 18.41 | F | C |
| ATOM | 6751 | O | LEU | F | 316 | −29.411 | 49.189 | 67.335 | 1.00 | 20.37 | F | O |
| ATOM | 6752 | N | ARG | F | 317 | −29.621 | 50.326 | 65.412 | 1.00 | 20.31 | F | N |
| ATOM | 6753 | CA | ARG | F | 317 | −31.027 | 50.015 | 65.276 | 1.00 | 19.94 | F | C |
| ATOM | 6754 | CB | ARG | F | 317 | −31.561 | 50.725 | 64.031 | 1.00 | 23.29 | F | C |
| ATOM | 6755 | CG | ARG | F | 317 | −32.983 | 50.400 | 63.646 | 1.00 | 28.27 | F | C |
| ATOM | 6756 | CD | ARG | F | 317 | −33.502 | 51.416 | 62.608 | 1.00 | 35.96 | F | C |
| ATOM | 6757 | NE | ARG | F | 317 | −32.581 | 51.630 | 61.481 | 1.00 | 39.88 | F | N |
| ATOM | 6758 | CZ | ARG | F | 317 | −31.853 | 52.731 | 61.294 | 1.00 | 41.46 | F | C |
| ATOM | 6759 | NH1 | ARG | F | 317 | −31.925 | 53.740 | 62.162 | 1.00 | 43.34 | F | N |
| ATOM | 6760 | NH2 | ARG | F | 317 | −31.063 | 52.833 | 60.229 | 1.00 | 40.35 | F | N |
| ATOM | 6761 | C | ARG | F | 317 | −31.261 | 48.498 | 65.196 | 1.00 | 19.78 | F | C |
| ATOM | 6762 | O | ARG | F | 317 | −32.237 | 47.993 | 65.738 | 1.00 | 23.17 | F | O |
| ATOM | 6763 | N | PHE | F | 318 | −30.371 | 47.764 | 64.537 | 1.00 | 16.94 | F | N |
| ATOM | 6764 | CA | PHE | F | 318 | −30.556 | 46.326 | 64.417 | 1.00 | 15.09 | F | C |
| ATOM | 6765 | CB | PHE | F | 318 | −29.633 | 45.740 | 63.345 | 1.00 | 15.85 | F | C |
| ATOM | 6766 | CG | PHE | F | 318 | −29.815 | 44.253 | 63.144 | 1.00 | 14.73 | F | C |
| ATOM | 6767 | CD1 | PHE | F | 318 | −30.759 | 43.773 | 62.249 | 1.00 | 13.94 | F | C |
| ATOM | 6768 | CD2 | PHE | F | 318 | −29.068 | 43.340 | 63.882 | 1.00 | 10.50 | F | C |
| ATOM | 6769 | CE1 | PHE | F | 318 | −30.958 | 42.398 | 62.094 | 1.00 | 17.21 | F | C |
| ATOM | 6770 | CE2 | PHE | F | 318 | −29.256 | 41.977 | 63.738 | 1.00 | 12.25 | F | C |
| ATOM | 6771 | CZ | PHE | F | 318 | −30.200 | 41.498 | 62.846 | 1.00 | 14.51 | F | C |
| ATOM | 6772 | C | PHE | F | 318 | −30.306 | 45.585 | 65.727 | 1.00 | 17.12 | F | C |
| ATOM | 6773 | O | PHE | F | 318 | −30.983 | 44.596 | 66.046 | 1.00 | 17.07 | F | O |
| ATOM | 6774 | N | ILE | F | 319 | −29.309 | 46.032 | 66.475 | 1.00 | 15.68 | F | N |
| ATOM | 6775 | CA | ILE | F | 319 | −28.999 | 45.388 | 67.729 | 1.00 | 14.92 | F | C |
| ATOM | 6776 | CB | ILE | F | 319 | −27.833 | 46.082 | 68.415 | 1.00 | 15.32 | F | C |
| ATOM | 6777 | CG2 | ILE | F | 319 | −27.701 | 45.595 | 69.846 | 1.00 | 15.06 | F | C |
| ATOM | 6778 | CG1 | ILE | F | 319 | −26.549 | 45.780 | 67.642 | 1.00 | 15.42 | F | C |
| ATOM | 6779 | CD1 | ILE | F | 319 | −25.376 | 46.629 | 68.075 | 1.00 | 15.22 | F | C |
| ATOM | 6780 | C | ILE | F | 319 | −30.237 | 45.445 | 68.615 | 1.00 | 17.91 | F | C |
| ATOM | 6781 | O | ILE | F | 319 | −30.662 | 44.423 | 69.154 | 1.00 | 18.17 | F | O |
| ATOM | 6782 | N | LYS | F | 320 | −30.821 | 46.637 | 68.740 | 1.00 | 17.44 | F | N |
| ATOM | 6783 | CA | LYS | F | 320 | −32.009 | 46.832 | 69.559 | 1.00 | 19.11 | F | C |
| ATOM | 6784 | CB | LYS | F | 320 | −32.381 | 48.309 | 69.592 | 1.00 | 19.27 | F | C |
| ATOM | 6785 | CG | LYS | F | 320 | −31.382 | 49.159 | 70.337 | 1.00 | 19.41 | F | C |
| ATOM | 6786 | CD | LYS | F | 320 | −31.757 | 50.625 | 70.291 | 1.00 | 17.53 | F | C |
| ATOM | 6787 | CE | LYS | F | 320 | −30.678 | 51.466 | 70.935 | 1.00 | 17.55 | F | C |
| ATOM | 6788 | NZ | LYS | F | 320 | −31.243 | 52.695 | 71.510 | 1.00 | 20.02 | F | N |
| ATOM | 6789 | C | LYS | F | 320 | −33.200 | 46.013 | 69.072 | 1.00 | 24.27 | F | C |
| ATOM | 6790 | O | LYS | F | 320 | −33.956 | 45.465 | 69.877 | 1.00 | 27.07 | F | O |
| ATOM | 6791 | N | LYS | F | 321 | −33.379 | 45.933 | 67.759 | 1.00 | 24.92 | F | N |
| ATOM | 6792 | CA | LYS | F | 321 | −34.485 | 45.158 | 67.205 | 1.00 | 25.91 | F | C |
| ATOM | 6793 | CB | LYS | F | 321 | −34.617 | 45.414 | 65.699 | 1.00 | 26.08 | F | C |
| ATOM | 6794 | CG | LYS | F | 321 | −35.889 | 44.860 | 65.089 | 1.00 | 29.25 | F | C |
| ATOM | 6795 | CD | LYS | F | 321 | −37.135 | 45.427 | 65.773 | 1.00 | 36.72 | F | C |
| ATOM | 6796 | CE | LYS | F | 321 | −38.420 | 45.040 | 65.030 | 1.00 | 39.28 | F | C |
| ATOM | 6797 | NZ | LYS | F | 321 | −38.643 | 43.554 | 65.031 | 1.00 | 42.65 | F | N |
| ATOM | 6798 | C | LYS | F | 321 | −34.263 | 43.671 | 67.464 | 1.00 | 24.89 | F | C |
| ATOM | 6799 | O | LYS | F | 321 | −35.202 | 42.940 | 67.751 | 1.00 | 26.56 | F | O |
| ATOM | 6800 | N | SER | F | 322 | −33.019 | 43.220 | 67.371 | 1.00 | 24.03 | F | N |
| ATOM | 6801 | CA | SER | F | 322 | −32.734 | 41.816 | 67.606 | 1.00 | 22.06 | F | C |
| ATOM | 6802 | CB | SER | F | 322 | −31.264 | 41.500 | 67.293 | 1.00 | 18.58 | F | C |
| ATOM | 6803 | OG | SER | F | 322 | −30.379 | 42.077 | 68.235 | 1.00 | 20.28 | F | O |
| ATOM | 6804 | C | SER | F | 322 | −33.063 | 41.440 | 69.045 | 1.00 | 24.91 | F | C |
| ATOM | 6805 | O | SER | F | 322 | −33.481 | 40.316 | 69.320 | 1.00 | 24.50 | F | O |
| ATOM | 6806 | N | TYR | F | 323 | −32.878 | 42.379 | 69.967 | 1.00 | 25.57 | F | N |
| ATOM | 6807 | CA | TYR | F | 323 | −33.175 | 42.112 | 71.366 | 1.00 | 28.47 | F | C |
| ATOM | 6808 | CB | TYR | F | 323 | −32.541 | 43.170 | 72.251 | 1.00 | 30.05 | F | C |
| ATOM | 6809 | CG | TYR | F | 323 | −32.781 | 42.932 | 73.718 | 1.00 | 33.06 | F | C |
| ATOM | 6810 | CD1 | TYR | F | 323 | −33.770 | 43.635 | 74.401 | 1.00 | 34.08 | F | C |
| ATOM | 6811 | CE1 | TYR | F | 323 | −33.985 | 43.433 | 75.757 | 1.00 | 35.76 | F | C |
| ATOM | 6812 | CD2 | TYR | F | 323 | −32.010 | 42.014 | 74.430 | 1.00 | 34.40 | F | C |
| ATOM | 6813 | CE2 | TYR | F | 323 | −32.215 | 41.803 | 75.785 | 1.00 | 36.12 | F | C |
| ATOM | 6814 | CZ | TYR | F | 323 | −33.204 | 42.517 | 76.442 | 1.00 | 37.80 | F | C |
| ATOM | 6815 | OH | TYR | F | 323 | −33.406 | 42.319 | 77.789 | 1.00 | 44.59 | F | O |
| ATOM | 6816 | C | TYR | F | 323 | −34.683 | 42.089 | 71.603 | 1.00 | 29.83 | F | C |
| ATOM | 6817 | O | TYR | F | 323 | −35.186 | 41.312 | 72.408 | 1.00 | 29.27 | F | O |
| ATOM | 6818 | N | GLN | F | 324 | −35.403 | 42.945 | 70.888 | 1.00 | 31.61 | F | N |
| ATOM | 6819 | CA | GLN | F | 324 | −36.845 | 43.012 | 71.023 | 1.00 | 31.96 | F | C |
| ATOM | 6820 | CB | GLN | F | 324 | −37.407 | 44.150 | 70.160 | 1.00 | 34.75 | F | C |
| ATOM | 6821 | CG | GLN | F | 324 | −38.935 | 44.209 | 70.089 | 1.00 | 41.20 | F | C |
| ATOM | 6822 | CD | GLN | F | 324 | −39.442 | 44.868 | 68.805 | 1.00 | 46.24 | F | C |
| ATOM | 6823 | OE1 | GLN | F | 324 | −39.188 | 46.056 | 68.558 | 1.00 | 48.31 | F | O |
| ATOM | 6824 | NE2 | GLN | F | 324 | −40.160 | 44.097 | 67.979 | 1.00 | 45.74 | F | N |
| ATOM | 6825 | C | GLN | F | 324 | −37.468 | 41.692 | 70.603 | 1.00 | 30.33 | F | C |
| ATOM | 6826 | O | GLN | F | 324 | −38.433 | 41.241 | 71.204 | 1.00 | 31.58 | F | O |
| ATOM | 6827 | N | VAL | F | 325 | −36.901 | 41.054 | 69.590 | 1.00 | 28.43 | F | N |
| ATOM | 6828 | CA | VAL | F | 325 | −37.467 | 39.812 | 69.106 | 1.00 | 27.77 | F | C |
| ATOM | 6829 | CB | VAL | F | 325 | −37.679 | 39.873 | 67.551 | 1.00 | 27.71 | F | C |
| ATOM | 6830 | CG1 | VAL | F | 325 | −38.161 | 41.249 | 67.135 | 1.00 | 27.26 | F | C |
| ATOM | 6831 | CG2 | VAL | F | 325 | −36.402 | 39.530 | 66.837 | 1.00 | 28.13 | F | C |
| ATOM | 6832 | C | VAL | F | 325 | −36.724 | 38.513 | 69.453 | 1.00 | 27.53 | F | C |
| ATOM | 6833 | O | VAL | F | 325 | −37.298 | 37.431 | 69.348 | 1.00 | 28.07 | F | O |
| ATOM | 6834 | N | ASP | F | 326 | −35.469 | 38.596 | 69.880 | 1.00 | 24.95 | F | N |
| ATOM | 6835 | CA | ASP | F | 326 | −34.716 | 37.371 | 70.174 | 1.00 | 23.44 | F | C |
| ATOM | 6836 | CB | ASP | F | 326 | −33.600 | 37.160 | 69.139 | 1.00 | 24.26 | F | C |
| ATOM | 6837 | CG | ASP | F | 326 | −34.106 | 36.639 | 67.809 | 1.00 | 25.84 | F | C |
| ATOM | 6838 | OD1 | ASP | F | 326 | −35.314 | 36.327 | 67.692 | 1.00 | 26.86 | F | O |
| ATOM | 6839 | OD2 | ASP | F | 326 | −33.275 | 36.543 | 66.878 | 1.00 | 22.89 | F | O |
| ATOM | 6840 | C | ASP | F | 326 | −34.063 | 37.341 | 71.543 | 1.00 | 22.24 | F | C |
| ATOM | 6841 | O | ASP | F | 326 | −33.177 | 36.524 | 71.775 | 1.00 | 22.51 | F | O |
| ATOM | 6842 | N | ALA | F | 327 | −34.477 | 38.222 | 72.444 | 1.00 | 23.26 | F | N |
| ATOM | 6843 | CA | ALA | F | 327 | −33.879 | 38.270 | 73.782 | 1.00 | 24.39 | F | C |
| ATOM | 6844 | CB | ALA | F | 327 | −34.703 | 39.180 | 74.684 | 1.00 | 22.42 | F | C |
| ATOM | 6845 | C | ALA | F | 327 | −33.732 | 36.885 | 74.425 | 1.00 | 26.02 | F | C |
| ATOM | 6846 | O | ALA | F | 327 | −32.797 | 36.638 | 75.185 | 1.00 | 24.93 | F | O |
| ATOM | 6847 | N | ASP | F | 328 | −34.650 | 35.980 | 74.102 | 1.00 | 28.75 | F | N |
| ATOM | 6848 | CA | ASP | F | 328 | −34.621 | 34.639 | 74.664 | 1.00 | 30.68 | F | C |
| ATOM | 6849 | CB | ASP | F | 328 | −36.028 | 34.241 | 75.136 | 1.00 | 31.55 | F | C |
| ATOM | 6850 | CG | ASP | F | 328 | −36.535 | 35.114 | 76.280 | 1.00 | 33.55 | F | C |
| ATOM | 6851 | OD1 | ASP | F | 328 | −35.719 | 35.609 | 77.092 | 1.00 | 34.34 | F | O |
| ATOM | 6852 | OD2 | ASP | F | 328 | −37.764 | 35.304 | 76.368 | 1.00 | 37.72 | F | O |
| ATOM | 6853 | C | ASP | F | 328 | −34.077 | 33.566 | 73.722 | 1.00 | 30.64 | F | C |
| ATOM | 6854 | O | ASP | F | 328 | −34.159 | 32.382 | 74.037 | 1.00 | 31.36 | F | O |
| ATOM | 6855 | N | ARG | F | 329 | −33.517 | 33.962 | 72.580 | 1.00 | 28.05 | F | N |
| ATOM | 6856 | CA | ARG | F | 329 | −32.973 | 32.984 | 71.640 | 1.00 | 25.36 | F | C |
| ATOM | 6857 | CB | ARG | F | 329 | −32.889 | 33.577 | 70.227 | 1.00 | 29.45 | F | C |
| ATOM | 6858 | CG | ARG | F | 329 | −33.054 | 32.551 | 69.103 | 1.00 | 31.77 | F | C |
| ATOM | 6859 | CD | ARG | F | 329 | −31.881 | 32.535 | 68.115 | 1.00 | 30.23 | F | C |
| ATOM | 6860 | NE | ARG | F | 329 | −32.082 | 33.479 | 67.021 | 1.00 | 30.15 | F | N |
| ATOM | 6861 | CZ | ARG | F | 329 | −31.789 | 33.253 | 65.741 | 1.00 | 29.15 | F | C |
| ATOM | 6862 | NH1 | ARG | F | 329 | −31.271 | 32.101 | 65.342 | 1.00 | 27.75 | F | N |
| ATOM | 6863 | NH2 | ARG | F | 329 | −32.011 | 34.206 | 64.853 | 1.00 | 27.00 | F | N |
| ATOM | 6864 | C | ARG | F | 329 | −31.572 | 32.596 | 72.089 | 1.00 | 25.39 | F | C |
| ATOM | 6865 | O | ARG | F | 329 | −30.795 | 33.458 | 72.495 | 1.00 | 24.39 | F | O |
| ATOM | 6866 | N | VAL | F | 330 | −31.235 | 31.312 | 72.034 | 1.00 | 22.59 | F | N |
| ATOM | 6867 | CA | VAL | F | 330 | −29.892 | 30.928 | 72.425 | 1.00 | 24.27 | F | C |
| ATOM | 6868 | CB | VAL | F | 330 | −29.718 | 29.408 | 72.586 | 1.00 | 23.58 | F | C |
| ATOM | 6869 | CG1 | VAL | F | 330 | −28.254 | 29.082 | 72.854 | 1.00 | 17.62 | F | C |
| ATOM | 6870 | CG2 | VAL | F | 330 | −30.577 | 28.914 | 73.735 | 1.00 | 23.90 | F | C |
| ATOM | 6871 | C | VAL | F | 330 | −29.084 | 31.421 | 71.252 | 1.00 | 27.66 | F | C |
| ATOM | 6872 | O | VAL | F | 330 | −29.361 | 31.083 | 70.102 | 1.00 | 28.34 | F | O |
| ATOM | 6873 | N | VAL | F | 331 | −28.063 | 32.208 | 71.537 | 1.00 | 28.36 | F | N |
| ATOM | 6874 | CA | VAL | F | 331 | −27.305 | 32.803 | 70.466 | 1.00 | 29.30 | F | C |
| ATOM | 6875 | CB | VAL | F | 331 | −27.778 | 34.271 | 70.342 | 1.00 | 28.56 | F | C |
| ATOM | 6876 | CG1 | VAL | F | 331 | −26.888 | 35.195 | 71.163 | 1.00 | 23.87 | F | C |
| ATOM | 6877 | CG2 | VAL | F | 331 | −27.858 | 34.672 | 68.918 | 1.00 | 31.24 | F | C |
| ATOM | 6878 | C | VAL | F | 331 | −25.798 | 32.729 | 70.640 | 1.00 | 32.20 | F | C |
| ATOM | 6879 | O | VAL | F | 331 | −25.049 | 32.989 | 69.709 | 1.00 | 33.88 | F | O |
| ATOM | 6880 | N | TYR | F | 332 | −25.355 | 32.349 | 71.830 | 1.00 | 35.62 | F | N |
| ATOM | 6881 | CA | TYR | F | 332 | −23.930 | 32.292 | 72.141 | 1.00 | 37.85 | F | C |
| ATOM | 6882 | CB | TYR | F | 332 | −23.569 | 33.563 | 72.922 | 1.00 | 36.22 | F | C |
| ATOM | 6883 | CG | TYR | F | 332 | −22.175 | 33.625 | 73.491 | 1.00 | 37.83 | F | C |
| ATOM | 6884 | CD1 | TYR | F | 332 | −21.131 | 34.214 | 72.772 | 1.00 | 36.09 | F | C |
| ATOM | 6885 | CE1 | TYR | F | 332 | −19.848 | 34.326 | 73.315 | 1.00 | 35.10 | F | C |
| ATOM | 6886 | CD2 | TYR | F | 332 | −21.904 | 33.141 | 74.777 | 1.00 | 41.34 | F | C |
| ATOM | 6887 | CE2 | TYR | F | 332 | −20.624 | 33.247 | 75.336 | 1.00 | 42.01 | F | C |
| ATOM | 6888 | CZ | TYR | F | 332 | −19.604 | 33.840 | 74.603 | 1.00 | 41.87 | F | C |
| ATOM | 6889 | OH | TYR | F | 332 | −18.356 | 33.946 | 75.183 | 1.00 | 43.26 | F | O |
| ATOM | 6890 | C | TYR | F | 332 | −23.648 | 31.034 | 72.958 | 1.00 | 41.23 | F | C |
| ATOM | 6891 | O | TYR | F | 332 | −24.493 | 30.585 | 73.740 | 1.00 | 43.15 | F | O |
| ATOM | 6892 | N | SER | F | 333 | −22.465 | 30.458 | 72.788 | 1.00 | 44.67 | F | N |
| ATOM | 6893 | CA | SER | F | 333 | −22.143 | 29.240 | 73.517 | 1.00 | 50.39 | F | C |
| ATOM | 6894 | CB | SER | F | 333 | −21.678 | 28.163 | 72.536 | 1.00 | 47.88 | F | C |
| ATOM | 6895 | OG | SER | F | 333 | −21.496 | 26.928 | 73.204 | 1.00 | 51.81 | F | O |
| ATOM | 6896 | C | SER | F | 333 | −21.113 | 29.367 | 74.651 | 1.00 | 55.47 | F | C |
| ATOM | 6897 | O | SER | F | 333 | −19.984 | 29.849 | 74.442 | 1.00 | 55.38 | F | O |
| ATOM | 6898 | N | THR | F | 334 | −21.518 | 28.932 | 75.851 | 1.00 | 57.60 | F | N |
| ATOM | 6899 | CA | THR | F | 334 | −20.640 | 28.939 | 77.025 | 1.00 | 59.19 | F | C |
| ATOM | 6900 | CB | THR | F | 334 | −21.018 | 30.060 | 78.053 | 1.00 | 59.06 | F | C |
| ATOM | 6901 | OG1 | THR | F | 334 | −19.920 | 30.979 | 78.172 | 1.00 | 57.91 | F | O |
| ATOM | 6902 | CG2 | THR | F | 334 | −21.321 | 29.465 | 79.445 | 1.00 | 58.20 | F | C |
| ATOM | 6903 | C | THR | F | 334 | −20.751 | 27.561 | 77.675 | 1.00 | 59.42 | F | C |
| ATOM | 6904 | O | THR | F | 334 | −21.838 | 26.980 | 77.726 | 1.00 | 56.57 | F | O |
| ATOM | 6905 | N | LYS | F | 335 | −19.616 | 27.053 | 78.154 | 1.00 | 60.40 | F | N |
| ATOM | 6906 | CA | LYS | F | 335 | −19.534 | 25.737 | 78.776 | 1.00 | 60.96 | F | C |
| ATOM | 6907 | CB | LYS | F | 335 | −18.293 | 25.652 | 79.668 | 1.00 | 58.80 | F | C |
| ATOM | 6908 | CG | LYS | F | 335 | −17.660 | 24.260 | 79.696 | 1.00 | 59.23 | F | C |
| ATOM | 6909 | CD | LYS | F | 335 | −18.666 | 23.152 | 80.074 | 1.00 | 58.66 | F | C |
| ATOM | 6910 | CE | LYS | F | 335 | −18.710 | 22.039 | 79.027 | 1.00 | 58.75 | F | C |
| ATOM | 6911 | NZ | LYS | F | 335 | −18.701 | 20.677 | 79.643 | 1.00 | 56.66 | F | N |
| ATOM | 6912 | C | LYS | F | 335 | −20.749 | 25.265 | 79.576 | 1.00 | 62.08 | F | C |
| ATOM | 6913 | O | LYS | F | 335 | −21.543 | 24.448 | 79.092 | 1.00 | 64.08 | F | O |
| ATOM | 6914 | N | GLU | F | 336 | −20.882 | 25.753 | 80.805 | 1.00 | 63.02 | F | N |
| ATOM | 6915 | CA | GLU | F | 336 | −21.991 | 25.333 | 81.660 | 1.00 | 63.22 | F | C |
| ATOM | 6916 | CB | GLU | F | 336 | −21.846 | 25.941 | 83.066 | 1.00 | 64.79 | F | C |
| ATOM | 6917 | CG | GLU | F | 336 | −21.900 | 24.915 | 84.213 | 1.00 | 65.27 | F | C |
| ATOM | 6918 | CD | GLU | F | 336 | −21.938 | 23.465 | 83.730 | 1.00 | 66.65 | F | C |
| ATOM | 6919 | OE1 | GLU | F | 336 | −23.054 | 22.921 | 83.539 | 1.00 | 66.80 | F | O |
| ATOM | 6920 | OE2 | GLU | F | 336 | −20.850 | 22.872 | 83.542 | 1.00 | 66.77 | F | O |
| ATOM | 6921 | C | GLU | F | 336 | −23.355 | 25.689 | 81.073 | 1.00 | 61.73 | F | C |
| ATOM | 6922 | O | GLU | F | 336 | −24.370 | 25.061 | 81.405 | 1.00 | 60.03 | F | O |
| ATOM | 6923 | N | LYS | F | 337 | −23.376 | 26.683 | 80.188 | 1.00 | 60.47 | F | N |
| ATOM | 6924 | CA | LYS | F | 337 | −24.632 | 27.102 | 79.577 | 1.00 | 58.65 | F | C |
| ATOM | 6925 | CB | LYS | F | 337 | −25.489 | 27.826 | 80.627 | 1.00 | 58.17 | F | C |
| ATOM | 6926 | CG | LYS | F | 337 | −26.842 | 28.281 | 80.131 | 1.00 | 55.46 | F | C |
| ATOM | 6927 | CD | LYS | F | 337 | −27.518 | 29.179 | 81.148 | 1.00 | 53.50 | F | C |
| ATOM | 6928 | CE | LYS | F | 337 | −28.769 | 29.808 | 80.553 | 1.00 | 53.75 | F | C |
| ATOM | 6929 | NZ | LYS | F | 337 | −30.046 | 29.222 | 81.046 | 1.00 | 51.94 | F | N |
| ATOM | 6930 | C | LYS | F | 337 | −24.458 | 28.000 | 78.347 | 1.00 | 57.10 | F | C |
| ATOM | 6931 | O | LYS | F | 337 | −23.697 | 28.967 | 78.363 | 1.00 | 59.14 | F | O |
| ATOM | 6932 | N | ASN | F | 338 | −25.153 | 27.664 | 77.269 | 1.00 | 53.17 | F | N |
| ATOM | 6933 | CA | ASN | F | 338 | −25.095 | 28.484 | 76.072 | 1.00 | 46.82 | F | C |
| ATOM | 6934 | CB | ASN | F | 338 | −25.678 | 27.721 | 74.875 | 1.00 | 48.36 | F | C |
| ATOM | 6935 | CG | ASN | F | 338 | −24.985 | 26.384 | 74.635 | 1.00 | 49.36 | F | C |
| ATOM | 6936 | OD1 | ASN | F | 338 | −23.771 | 26.327 | 74.399 | 1.00 | 49.44 | F | O |
| ATOM | 6937 | ND2 | ASN | F | 338 | −25.758 | 25.299 | 74.692 | 1.00 | 49.53 | F | N |
| ATOM | 6938 | C | ASN | F | 338 | −25.992 | 29.657 | 76.455 | 1.00 | 43.42 | F | C |
| ATOM | 6939 | O | ASN | F | 338 | −27.059 | 29.449 | 77.030 | 1.00 | 46.14 | F | O |
| ATOM | 6940 | N | LEU | F | 339 | −25.566 | 30.879 | 76.160 | 1.00 | 35.99 | F | N |
| ATOM | 6941 | CA | LEU | F | 339 | −26.351 | 32.053 | 76.515 | 1.00 | 32.26 | F | C |
| ATOM | 6942 | CB | LEU | F | 339 | −25.427 | 33.234 | 76.739 | 1.00 | 31.87 | F | C |
| ATOM | 6943 | CG | LEU | F | 339 | −24.173 | 32.875 | 77.522 | 1.00 | 33.21 | F | C |
| ATOM | 6944 | CD1 | LEU | F | 339 | −23.328 | 34.117 | 77.706 | 1.00 | 34.29 | F | C |
| ATOM | 6945 | CD2 | LEU | F | 339 | −24.569 | 32.285 | 78.867 | 1.00 | 35.86 | F | C |
| ATOM | 6946 | C | LEU | F | 339 | −27.403 | 32.477 | 75.531 | 1.00 | 28.85 | F | C |
| ATOM | 6947 | O | LEU | F | 339 | −27.262 | 32.265 | 74.337 | 1.00 | 28.83 | F | O |
| ATOM | 6948 | N | THR | F | 340 | −28.464 | 33.079 | 76.044 | 1.00 | 28.23 | F | N |
| ATOM | 6949 | CA | THR | F | 340 | −29.503 | 33.601 | 75.183 | 1.00 | 29.14 | F | C |
| ATOM | 6950 | CB | THR | F | 340 | −30.867 | 33.646 | 75.893 | 1.00 | 27.91 | F | C |
| ATOM | 6951 | OG1 | THR | F | 340 | −30.832 | 34.618 | 76.943 | 1.00 | 26.32 | F | O |
| ATOM | 6952 | CG2 | THR | F | 340 | −31.203 | 32.286 | 76.454 | 1.00 | 25.95 | F | C |
| ATOM | 6953 | C | THR | F | 340 | −29.020 | 35.026 | 74.895 | 1.00 | 29.73 | F | C |
| ATOM | 6954 | O | THR | F | 340 | −28.038 | 35.478 | 75.500 | 1.00 | 29.63 | F | O |
| ATOM | 6955 | N | LEU | F | 341 | −29.671 | 35.730 | 73.972 | 1.00 | 29.43 | F | N |
| ATOM | 6956 | CA | LEU | F | 341 | −29.263 | 37.103 | 73.673 | 1.00 | 29.11 | F | C |
| ATOM | 6957 | CB | LEU | F | 341 | −30.227 | 37.747 | 72.659 | 1.00 | 25.79 | F | C |
| ATOM | 6958 | CG | LEU | F | 341 | −29.830 | 39.122 | 72.094 | 1.00 | 24.74 | F | C |
| ATOM | 6959 | CD1 | LEU | F | 341 | −28.399 | 39.078 | 71.562 | 1.00 | 23.48 | F | C |
| ATOM | 6960 | CD2 | LEU | F | 341 | −30.783 | 39.530 | 70.996 | 1.00 | 21.15 | F | C |
| ATOM | 6961 | C | LEU | F | 341 | −29.250 | 37.914 | 74.979 | 1.00 | 29.05 | F | C |
| ATOM | 6962 | O | LEU | F | 341 | −28.269 | 38.606 | 75.290 | 1.00 | 25.25 | F | O |
| ATOM | 6963 | N | LYS | F | 342 | −30.341 | 37.803 | 75.737 | 1.00 | 28.27 | F | N |
| ATOM | 6964 | CA | LYS | F | 342 | −30.487 | 38.504 | 77.007 | 1.00 | 27.59 | F | C |
| ATOM | 6965 | CB | LYS | F | 342 | −31.801 | 38.080 | 77.679 | 1.00 | 29.72 | F | C |
| ATOM | 6966 | CG | LYS | F | 342 | −32.206 | 38.939 | 78.871 | 1.00 | 34.18 | F | C |
| ATOM | 6967 | CD | LYS | F | 342 | −33.616 | 38.608 | 79.330 | 1.00 | 35.72 | F | C |
| ATOM | 6968 | CE | LYS | F | 342 | −34.474 | 39.865 | 79.479 | 1.00 | 41.88 | F | C |
| ATOM | 6969 | NZ | LYS | F | 342 | −35.558 | 39.981 | 78.440 | 1.00 | 44.15 | F | N |
| ATOM | 6970 | C | LYS | F | 342 | −29.306 | 38.207 | 77.931 | 1.00 | 25.91 | F | C |
| ATOM | 6971 | O | LYS | F | 342 | −28.699 | 39.116 | 78.493 | 1.00 | 25.99 | F | O |
| ATOM | 6972 | N | GLN | F | 343 | −28.962 | 36.931 | 78.065 | 1.00 | 24.26 | F | N |
| ATOM | 6973 | CA | GLN | F | 343 | −27.861 | 36.537 | 78.944 | 1.00 | 25.92 | F | C |
| ATOM | 6974 | CB | GLN | F | 343 | −27.799 | 35.018 | 79.105 | 1.00 | 27.15 | F | C |
| ATOM | 6975 | CG | GLN | F | 343 | −28.914 | 34.424 | 79.959 | 1.00 | 29.20 | F | C |
| ATOM | 6976 | CD | GLN | F | 343 | −29.043 | 32.929 | 79.762 | 1.00 | 28.62 | F | C |
| ATOM | 6977 | OE1 | GLN | F | 343 | −28.116 | 32.282 | 79.305 | 1.00 | 27.77 | F | O |
| ATOM | 6978 | NE2 | GLN | F | 343 | −30.195 | 32.382 | 80.095 | 1.00 | 32.07 | F | N |
| ATOM | 6979 | C | GLN | F | 343 | −26.502 | 37.023 | 78.488 | 1.00 | 25.55 | F | C |
| ATOM | 6980 | O | GLN | F | 343 | −25.640 | 37.332 | 79.303 | 1.00 | 25.33 | F | O |
| ATOM | 6981 | N | LEU | F | 344 | −26.283 | 37.063 | 77.184 | 1.00 | 25.66 | F | N |
| ATOM | 6982 | CA | LEU | F | 344 | −24.998 | 37.539 | 76.692 | 1.00 | 24.89 | F | C |
| ATOM | 6983 | CE | LEU | F | 344 | −24.871 | 37.333 | 75.179 | 1.00 | 25.65 | F | C |
| ATOM | 6984 | CG | LEU | F | 344 | −23.692 | 38.069 | 74.525 | 1.00 | 22.92 | F | C |
| ATOM | 6985 | CD1 | LEU | F | 344 | −22.371 | 37.490 | 75.000 | 1.00 | 20.69 | F | C |
| ATOM | 6986 | CD2 | LEU | F | 344 | −23.797 | 37.955 | 73.023 | 1.00 | 22.61 | F | C |
| ATOM | 6987 | C | LEU | F | 344 | −24.849 | 39.022 | 77.020 | 1.00 | 24.21 | F | C |
| ATOM | 6988 | O | LEU | F | 344 | −23.753 | 39.481 | 77.324 | 1.00 | 23.91 | F | O |
| ATOM | 6989 | N | PHE | F | 345 | −25.946 | 39.772 | 76.951 | 1.00 | 23.49 | F | N |
| ATOM | 6990 | CA | PHE | F | 345 | −25.890 | 41.191 | 77.272 | 1.00 | 25.46 | F | C |
| ATOM | 6991 | CB | PHE | F | 345 | −27.159 | 41.908 | 76.798 | 1.00 | 25.25 | F | C |
| ATOM | 6992 | CG | PHE | F | 345 | −27.102 | 42.324 | 75.358 | 1.00 | 27.61 | F | C |
| ATOM | 6993 | CD1 | PHE | F | 345 | −26.096 | 43.178 | 74.913 | 1.00 | 28.58 | F | C |
| ATOM | 6994 | CD2 | PHE | F | 345 | −28.018 | 41.824 | 74.432 | 1.00 | 27.15 | F | C |
| ATOM | 6995 | CE1 | PHE | F | 345 | −26.000 | 43.528 | 73.564 | 1.00 | 27.65 | F | C |
| ATOM | 6996 | CE2 | PHE | F | 345 | −27.928 | 42.166 | 73.089 | 1.00 | 26.84 | F | C |
| ATOM | 6997 | CZ | PHE | F | 345 | −26.918 | 43.018 | 72.652 | 1.00 | 25.91 | F | C |
| ATOM | 6998 | C | PHE | F | 345 | −25.701 | 41.369 | 78.773 | 1.00 | 27.10 | F | C |
| ATOM | 6999 | O | PHE | F | 345 | −25.050 | 42.319 | 79.206 | 1.00 | 25.27 | F | O |
| ATOM | 7000 | N | ASP | F | 346 | −26.272 | 40.460 | 79.565 | 1.00 | 29.80 | F | N |
| ATOM | 7001 | CA | ASP | F | 346 | −26.115 | 40.516 | 81.023 | 1.00 | 31.46 | F | C |
| ATOM | 7002 | CB | ASP | F | 346 | −26.931 | 39.419 | 81.701 | 1.00 | 36.01 | F | C |
| ATOM | 7003 | CG | ASP | F | 346 | −28.388 | 39.772 | 81.816 | 1.00 | 40.53 | F | C |
| ATOM | 7004 | OD1 | ASP | F | 346 | −28.799 | 40.814 | 81.260 | 1.00 | 44.78 | F | O |
| ATOM | 7005 | OD2 | ASP | F | 346 | −29.128 | 39.004 | 82.462 | 1.00 | 48.81 | F | O |
| ATOM | 7006 | C | ASP | F | 346 | −24.641 | 40.285 | 81.318 | 1.00 | 30.57 | F | C |
| ATOM | 7007 | O | ASP | F | 346 | −24.008 | 41.038 | 82.059 | 1.00 | 27.23 | F | O |
| ATOM | 7008 | N | LYS | F | 347 | −24.104 | 39.229 | 80.717 | 1.00 | 29.91 | F | N |
| ATOM | 7009 | CA | LYS | F | 347 | −22.710 | 38.878 | 80.880 | 1.00 | 30.64 | F | C |
| ATOM | 7010 | CB | LYS | F | 347 | −22.385 | 37.655 | 80.025 | 1.00 | 34.22 | F | C |
| ATOM | 7011 | CG | LYS | F | 347 | −20.932 | 37.208 | 80.086 | 1.00 | 38.78 | F | C |
| ATOM | 7012 | CD | LYS | F | 347 | −20.134 | 37.761 | 78.907 | 1.00 | 43.46 | F | C |
| ATOM | 7013 | CE | LYS | F | 347 | −19.456 | 36.652 | 78.105 | 1.00 | 45.14 | F | C |
| ATOM | 7014 | NZ | LYS | F | 347 | −18.881 | 35.593 | 78.987 | 1.00 | 47.17 | F | N |
| ATOM | 7015 | C | LYS | F | 347 | −21.829 | 40.051 | 80.467 | 1.00 | 33.86 | F | C |
| ATOM | 7016 | O | LYS | F | 347 | −20.727 | 40.234 | 80.986 | 1.00 | 34.97 | F | O |
| ATOM | 7017 | N | LEU | F | 348 | −22.317 | 40.856 | 79.530 | 1.00 | 34.36 | F | N |
| ATOM | 7018 | CA | LEU | F | 348 | −21.552 | 42.006 | 79.052 | 1.00 | 33.07 | F | C |
| ATOM | 7019 | CB | LEU | F | 348 | −21.868 | 42.288 | 77.574 | 1.00 | 30.92 | F | C |
| ATOM | 7020 | CG | LEU | F | 348 | −21.318 | 41.293 | 76.556 | 1.00 | 25.84 | F | C |
| ATOM | 7021 | CD1 | LEU | F | 348 | −21.773 | 41.687 | 75.174 | 1.00 | 25.68 | F | C |
| ATOM | 7022 | CD2 | LEU | F | 348 | −19.819 | 41.260 | 76.627 | 1.00 | 20.51 | F | C |
| ATOM | 7023 | C | LEU | F | 348 | −21.861 | 43.247 | 79.873 | 1.00 | 34.61 | F | C |
| ATOM | 7024 | O | LEU | F | 348 | −21.191 | 44.271 | 79.737 | 1.00 | 32.75 | F | O |
| ATOM | 7025 | N | LYS | F | 349 | −22.895 | 43.158 | 80.706 | 1.00 | 36.50 | F | N |
| ATOM | 7026 | CA | LYS | F | 349 | −23.294 | 44.270 | 81.557 | 1.00 | 37.39 | F | C |
| ATOM | 7027 | CB | LYS | F | 349 | −22.077 | 44.726 | 82.383 | 1.00 | 40.43 | F | C |
| ATOM | 7028 | CG | LYS | F | 349 | −22.199 | 46.091 | 83.063 | 1.00 | 47.97 | F | C |
| ATOM | 7029 | CD | LYS | F | 349 | −21.270 | 47.140 | 82.406 | 1.00 | 49.97 | F | C |
| ATOM | 7030 | CE | LYS | F | 349 | −21.871 | 48.554 | 82.445 | 1.00 | 48.97 | F | C |
| ATOM | 7031 | NZ | LYS | F | 349 | −22.450 | 48.907 | 83.783 | 1.00 | 47.43 | F | N |
| ATOM | 7032 | C | LYS | F | 349 | −23.888 | 45.431 | 80.743 | 1.00 | 36.08 | F | C |
| ATOM | 7033 | O | LYS | F | 349 | −23.537 | 46.595 | 80.935 | 1.00 | 35.22 | F | O |
| ATOM | 7034 | N | LEU | F | 350 | −24.802 | 45.121 | 79.830 | 1.00 | 35.07 | F | N |
| ATOM | 7035 | CA | LEU | F | 350 | −25.413 | 46.181 | 79.041 | 1.00 | 32.06 | F | C |
| ATOM | 7036 | CB | LEU | F | 350 | −24.718 | 46.331 | 77.689 | 1.00 | 32.66 | F | C |
| ATOM | 7037 | CG | LEU | F | 350 | −23.221 | 46.112 | 77.535 | 1.00 | 34.09 | F | C |
| ATOM | 7038 | CD1 | LEU | F | 350 | −22.922 | 45.609 | 76.122 | 1.00 | 30.77 | F | C |
| ATOM | 7039 | CD2 | LEU | F | 350 | −22.504 | 47.429 | 77.807 | 1.00 | 32.10 | F | C |
| ATOM | 7040 | C | LEU | F | 350 | −26.857 | 45.918 | 78.752 | 1.00 | 29.24 | F | C |
| ATOM | 7041 | O | LEU | F | 350 | −27.281 | 44.771 | 78.731 | 1.00 | 30.20 | F | O |
| ATOM | 7042 | N | HIS | F | 351 | −27.623 | 46.985 | 78.568 | 1.00 | 30.83 | F | N |
| ATOM | 7043 | CA | HIS | F | 351 | −28.998 | 46.805 | 78.148 | 1.00 | 34.61 | F | C |
| ATOM | 7044 | CB | HIS | F | 351 | −30.040 | 47.423 | 79.070 | 1.00 | 35.42 | F | C |
| ATOM | 7045 | CG | HIS | F | 351 | −31.432 | 47.056 | 78.664 | 1.00 | 37.88 | F | C |
| ATOM | 7046 | CD2 | HIS | F | 351 | −32.202 | 47.499 | 77.640 | 1.00 | 40.16 | F | C |
| ATOM | 7047 | ND1 | HIS | F | 351 | −32.117 | 45.999 | 79.226 | 1.00 | 40.38 | F | N |
| ATOM | 7048 | CE1 | HIS | F | 351 | −33.246 | 45.803 | 78.566 | 1.00 | 40.75 | F | C |
| ATOM | 7049 | NE2 | HIS | F | 351 | −33.321 | 46.700 | 77.598 | 1.00 | 41.74 | F | N |
| ATOM | 7050 | C | HIS | F | 351 | −29.092 | 47.483 | 76.792 | 1.00 | 34.30 | F | C |
| ATOM | 7051 | O | HIS | F | 351 | −29.026 | 48.708 | 76.698 | 1.00 | 34.70 | F | O |
| ATOM | 7052 | N | PRO | F | 352 | −29.262 | 46.689 | 75.728 | 1.00 | 32.50 | F | N |
| ATOM | 7053 | CD | PRO | F | 352 | −29.408 | 45.227 | 75.777 | 1.00 | 32.69 | F | C |
| ATOM | 7054 | CA | PRO | F | 352 | −29.360 | 47.196 | 74.361 | 1.00 | 32.64 | F | C |
| ATOM | 7055 | CB | PRO | F | 352 | −30.017 | 46.045 | 73.587 | 1.00 | 33.03 | F | C |
| ATOM | 7056 | CG | PRO | F | 352 | −30.279 | 44.951 | 74.607 | 1.00 | 34.95 | F | C |
| ATOM | 7057 | C | PRO | F | 352 | −30.131 | 48.499 | 74.202 | 1.00 | 30.66 | F | C |
| ATOM | 7058 | O | PRO | F | 352 | −29.733 | 49.364 | 73.419 | 1.00 | 30.80 | F | O |
| ATOM | 7059 | N | TYR | F | 353 | −31.214 | 48.654 | 74.955 | 1.00 | 27.44 | F | N |
| ATOM | 7060 | CA | TYR | F | 353 | −32.027 | 49.850 | 74.819 | 1.00 | 27.33 | F | C |
| ATOM | 7061 | CB | TYR | F | 353 | −33.371 | 49.637 | 75.501 | 1.00 | 29.34 | F | C |
| ATOM | 7062 | CG | TYR | F | 353 | −34.200 | 48.557 | 74.826 | 1.00 | 32.50 | F | C |
| ATOM | 7063 | CD1 | TYR | F | 353 | −33.831 | 48.035 | 73.574 | 1.00 | 31.86 | F | C |
| ATOM | 7064 | CE1 | TYR | F | 353 | −34.588 | 47.038 | 72.948 | 1.00 | 32.03 | F | C |
| ATOM | 7065 | CD2 | TYR | F | 353 | −35.351 | 48.053 | 75.434 | 1.00 | 32.92 | F | C |
| ATOM | 7066 | CE2 | TYR | F | 353 | −36.122 | 47.052 | 74.818 | 1.00 | 33.49 | F | C |
| ATOM | 7067 | CZ | TYR | F | 353 | −35.736 | 46.548 | 73.576 | 1.00 | 35.09 | F | C |
| ATOM | 7068 | OH | TYR | F | 353 | −36.496 | 45.558 | 72.973 | 1.00 | 33.97 | F | O |
| ATOM | 7069 | C | TYR | F | 353 | −31.383 | 51.138 | 75.285 | 1.00 | 27.34 | F | C |
| ATOM | 7070 | O | TYR | F | 353 | −31.811 | 52.224 | 74.888 | 1.00 | 29.31 | F | O |
| ATOM | 7071 | N | ASP | F | 354 | −30.348 | 51.032 | 75.110 | 1.00 | 26.02 | F | N |
| ATOM | 7072 | CA | ASP | F | 354 | −29.643 | 52.223 | 76.583 | 1.00 | 25.02 | F | C |
| ATOM | 7073 | CB | ASP | F | 354 | −29.062 | 51.995 | 77.974 | 1.00 | 29.81 | F | C |
| ATOM | 7074 | CG | ASP | F | 354 | −30.101 | 51.536 | 78.976 | 1.00 | 36.21 | F | C |
| ATOM | 7075 | OD1 | ASP | F | 354 | −31.291 | 51.910 | 78.839 | 1.00 | 33.73 | F | O |
| ATOM | 7076 | OD2 | ASP | F | 354 | −29.716 | 50.794 | 79.906 | 1.00 | 39.48 | F | O |
| ATOM | 7077 | C | ASP | F | 354 | −28.500 | 52.594 | 75.639 | 1.00 | 23.12 | F | C |
| ATOM | 7078 | O | ASP | F | 354 | −27.880 | 53.653 | 75.788 | 1.00 | 21.38 | F | O |
| ATOM | 7079 | N | LEU | F | 355 | −28.220 | 51.716 | 74.676 | 1.00 | 20.60 | F | N |
| ATOM | 7080 | CA | LEU | F | 355 | −27.150 | 51.956 | 73.730 | 1.00 | 17.90 | F | C |
| ATOM | 7081 | CB | LEU | F | 355 | −26.996 | 50.763 | 72.806 | 1.00 | 15.81 | F | C |
| ATOM | 7082 | CG | LEU | F | 355 | −26.272 | 49.613 | 73.516 | 1.00 | 20.13 | F | C |
| ATOM | 7083 | CD1 | LEU | F | 355 | −26.257 | 48.376 | 72.623 | 1.00 | 18.87 | F | C |
| ATOM | 7084 | CD2 | LEU | F | 355 | −24.851 | 50.032 | 73.880 | 1.00 | 15.37 | F | C |
| ATOM | 7085 | C | LEU | F | 355 | −27.372 | 53.238 | 72.944 | 1.00 | 16.66 | F | C |
| ATOM | 7086 | O | LEU | F | 355 | −28.490 | 53.652 | 72.693 | 1.00 | 15.40 | F | O |
| ATOM | 7087 | N | THR | F | 356 | −26.272 | 53.851 | 72.557 | 1.00 | 17.98 | F | N |
| ATOM | 7088 | CA | THR | F | 356 | −26.274 | 55.117 | 71.847 | 1.00 | 18.38 | F | C |
| ATOM | 7089 | CB | THR | F | 356 | −25.959 | 56.203 | 72.904 | 1.00 | 19.11 | F | C |
| ATOM | 7090 | OG1 | THR | F | 356 | −27.176 | 56.825 | 73.322 | 1.00 | 24.36 | F | O |
| ATOM | 7091 | CG2 | THR | F | 356 | −25.003 | 57.200 | 72.416 | 1.00 | 18.40 | F | C |
| ATOM | 7092 | C | THR | F | 356 | −25.142 | 54.970 | 70.823 | 1.00 | 18.48 | F | C |
| ATOM | 7093 | O | THR | F | 356 | −24.376 | 54.016 | 70.924 | 1.00 | 16.59 | F | O |
| ATOM | 7094 | N | VAL | F | 357 | −25.022 | 55.865 | 69.839 | 1.00 | 18.18 | F | N |
| ATOM | 7095 | CA | VAL | F | 357 | −23.901 | 55.709 | 68.918 | 1.00 | 17.45 | F | C |
| ATOM | 7096 | CB | VAL | F | 357 | −23.961 | 56.662 | 67.655 | 1.00 | 18.34 | F | C |
| ATOM | 7097 | CG1 | VAL | F | 357 | −25.273 | 56.446 | 66.893 | 1.00 | 16.27 | F | C |
| ATOM | 7098 | CG2 | VAL | F | 357 | −23.779 | 58.105 | 68.054 | 1.00 | 20.76 | F | C |
| ATOM | 7099 | C | VAL | F | 357 | −22.639 | 55.987 | 69.726 | 1.00 | 15.85 | F | C |
| ATOM | 7100 | O | VAL | F | 357 | −21.572 | 55.480 | 69.401 | 1.00 | 16.24 | F | O |
| ATOM | 7101 | N | ASP | F | 358 | −22.766 | 56.773 | 70.797 | 1.00 | 14.66 | F | N |
| ATOM | 7102 | CA | ASP | F | 358 | −21.614 | 57.081 | 71.652 | 1.00 | 14.01 | F | C |
| ATOM | 7103 | CB | ASP | F | 358 | −21.980 | 58.090 | 72.745 | 1.00 | 17.28 | F | C |
| ATOM | 7104 | CG | ASP | F | 358 | −22.236 | 59.489 | 72.210 | 1.00 | 19.42 | F | C |
| ATOM | 7105 | OD1 | ASP | F | 358 | −21.663 | 59.863 | 71.157 | 1.00 | 19.74 | F | O |
| ATOM | 7106 | OD2 | ASP | F | 358 | −23.019 | 60.219 | 72.865 | 1.00 | 23.49 | F | O |
| ATOM | 7107 | C | ASP | F | 358 | −21.117 | 55.811 | 72.329 | 1.00 | 13.32 | F | C |
| ATOM | 7108 | O | ASP | F | 358 | −19.915 | 55.519 | 72.328 | 1.00 | 15.19 | F | O |
| ATOM | 7109 | N | SER | F | 359 | −22.040 | 55.056 | 72.926 | 1.00 | 15.23 | F | N |
| ATOM | 7110 | CA | SER | F | 359 | −21.655 | 53.815 | 73.612 | 1.00 | 16.33 | F | C |
| ATOM | 7111 | CB | SER | F | 359 | −22.737 | 53.412 | 74.607 | 1.00 | 14.06 | F | C |
| ATOM | 7112 | OG | SER | F | 359 | −24.029 | 53.532 | 74.040 | 1.00 | 18.09 | F | O |
| ATOM | 7113 | C | SER | F | 359 | −21.360 | 52.683 | 72.606 | 1.00 | 16.88 | F | C |
| ATOM | 7114 | O | SER | F | 359 | −20.540 | 51.804 | 72.876 | 1.00 | 15.47 | F | O |
| ATOM | 7115 | N | LEU | F | 360 | −22.017 | 52.709 | 71.443 | 1.00 | 17.94 | F | N |
| ATOM | 7116 | CA | LEU | F | 360 | −21.759 | 51.709 | 70.393 | 1.00 | 17.40 | F | C |
| ATOM | 7117 | CB | LEU | F | 360 | −22.639 | 51.969 | 69.165 | 1.00 | 18.20 | F | C |
| ATOM | 7118 | CG | LEU | F | 360 | −22.421 | 51.055 | 67.949 | 1.00 | 19.78 | F | C |
| ATOM | 7119 | CD1 | LEU | F | 360 | −22.654 | 49.588 | 68.344 | 1.00 | 20.16 | F | C |
| ATOM | 7120 | CD2 | LEU | F | 360 | −23.380 | 51.478 | 66.814 | 1.00 | 15.62 | F | C |
| ATOM | 7121 | C | LEU | F | 360 | −20.279 | 51.863 | 70.035 | 1.00 | 17.97 | F | C |
| ATOM | 7122 | O | LEU | F | 360 | −19.582 | 50.880 | 69.803 | 1.00 | 19.76 | F | O |
| ATOM | 7123 | N | ASP | F | 361 | −19.816 | 53.110 | 69.985 | 1.00 | 18.41 | F | N |
| ATOM | 7124 | CA | ASP | F | 361 | −18.403 | 53.419 | 69.757 | 1.00 | 21.02 | F | C |
| ATOM | 7125 | CB | ASP | F | 361 | −17.621 | 53.106 | 71.053 | 1.00 | 23.19 | F | C |
| ATOM | 7126 | CG | ASP | F | 361 | −16.320 | 53.894 | 71.181 | 1.00 | 23.86 | F | C |
| ATOM | 7127 | OD1 | ASP | F | 361 | −16.220 | 55.000 | 70.621 | 1.00 | 29.52 | F | O |
| ATOM | 7128 | OD2 | ASP | F | 361 | −15.388 | 53.408 | 71.855 | 1.00 | 24.27 | F | O |
| ATOM | 7129 | C | ASP | F | 361 | −17.725 | 52.717 | 68.585 | 1.00 | 22.47 | F | C |
| ATOM | 7130 | O | ASP | F | 361 | −16.621 | 52.192 | 68.746 | 1.00 | 22.25 | F | O |
| ATOM | 7131 | N | VAL | F | 362 | −18.354 | 52.716 | 67.410 | 1.00 | 22.97 | F | N |
| ATOM | 7132 | CA | VAL | F | 362 | −17.745 | 52.059 | 66.249 | 1.00 | 26.44 | F | C |
| ATOM | 7133 | CB | VAL | F | 362 | −18.729 | 51.077 | 65.546 | 1.00 | 25.40 | F | C |
| ATOM | 7134 | CG1 | VAL | F | 362 | −19.063 | 49.914 | 66.483 | 1.00 | 24.15 | F | C |
| ATOM | 7135 | CG2 | VAL | F | 362 | −19.988 | 51.814 | 65.108 | 1.00 | 25.06 | F | C |
| ATOM | 7136 | C | VAL | F | 362 | −17.218 | 53.053 | 65.212 | 1.00 | 26.24 | F | C |
| ATOM | 7137 | O | VAL | F | 362 | −16.624 | 52.668 | 64.209 | 1.00 | 28.00 | F | O |
| ATOM | 7138 | N | HIS | F | 363 | −17.427 | 54.333 | 65.458 | 1.00 | 26.31 | F | N |
| ATOM | 7139 | CA | HIS | F | 363 | −16.958 | 55.342 | 64.534 | 1.00 | 27.47 | F | C |
| ATOM | 7140 | CB | HIS | F | 363 | −17.834 | 56.582 | 64.615 | 1.00 | 25.11 | F | C |
| ATOM | 7141 | CG | HIS | F | 363 | −18.068 | 57.235 | 63.292 | 1.00 | 29.56 | F | C |
| ATOM | 7142 | CD2 | HIS | F | 363 | −18.973 | 56.976 | 62.317 | 1.00 | 28.68 | F | C |
| ATOM | 7143 | ND1 | HIS | F | 363 | −17.304 | 58.290 | 62.839 | 1.00 | 28.88 | F | N |
| ATOM | 7144 | CE1 | HIS | F | 363 | −17.730 | 58.653 | 61.642 | 1.00 | 29.52 | F | C |
| ATOM | 7145 | NE2 | HIS | F | 363 | −18.741 | 57.872 | 61.303 | 1.00 | 28.81 | F | N |
| ATOM | 7146 | C | HIS | F | 363 | −15.520 | 55.717 | 64.840 | 1.00 | 30.44 | F | C |
| ATOM | 7147 | O | HIS | F | 363 | −15.146 | 55.873 | 66.002 | 1.00 | 29.12 | F | O |
| ATOM | 7148 | N | ALA | F | 364 | −14.714 | 55.859 | 63.791 | 1.00 | 32.89 | F | N |
| ATOM | 7149 | CA | ALA | F | 364 | −13.314 | 56.227 | 63.948 | 1.00 | 36.12 | F | C |
| ATOM | 7150 | CB | ALA | F | 364 | −12.572 | 56.029 | 62.629 | 1.00 | 34.99 | F | C |
| ATOM | 7151 | C | ALA | F | 364 | −13.211 | 57.682 | 64.408 | 1.00 | 38.55 | F | C |
| ATOM | 7152 | O | ALA | F | 364 | −14.147 | 58.466 | 64.245 | 1.00 | 37.78 | F | O |
| ATOM | 7153 | N | GLY | F | 365 | −12.070 | 58.034 | 64.992 | 1.00 | 43.62 | F | N |
| ATOM | 7154 | CA | GLY | F | 365 | −11.873 | 59.393 | 65.468 | 1.00 | 49.65 | F | C |
| ATOM | 7155 | C | GLY | F | 365 | −10.442 | 59.877 | 65.305 | 1.00 | 53.03 | F | C |
| ATOM | 7156 | O | GLY | F | 365 | −9.737 | 59.347 | 64.410 | 1.00 | 55.03 | F | O |
| ATOM | 7157 | OT | GLY | F | 365 | −10.019 | 60.785 | 66.067 | 1.00 | 54.78 | F | O |
| ATOM | 7158 | CB | LYS | G | 378 | −9.116 | 44.552 | 66.219 | 1.00 | 60.09 | G | C |
| ATOM | 7159 | CG | LYS | G | 378 | −9.261 | 43.361 | 67.170 | 1.00 | 62.23 | G | C |
| ATOM | 7160 | CD | LYS | G | 378 | −8.018 | 43.189 | 68.062 | 1.00 | 64.36 | G | C |
| ATOM | 7161 | CE | LYS | G | 378 | −7.127 | 42.022 | 67.610 | 1.00 | 64.56 | G | C |
| ATOM | 7162 | NZ | LYS | G | 378 | −5.862 | 41.918 | 68.405 | 1.00 | 63.84 | G | N |
| ATOM | 7163 | C | LYS | G | 378 | −11.132 | 45.983 | 66.593 | 1.00 | 57.27 | G | C |
| ATOM | 7164 | O | LYS | G | 378 | −10.748 | 46.045 | 67.766 | 1.00 | 57.38 | G | O |
| ATOM | 7165 | N | LYS | G | 378 | −10.164 | 45.756 | 64.315 | 1.00 | 59.13 | G | N |
| ATOM | 7166 | CA | LYS | G | 378 | −10.433 | 45.053 | 65.604 | 1.00 | 58.44 | G | C |
| ATOM | 7167 | N | TYR | G | 379 | −12.146 | 46.712 | 66.123 | 1.00 | 54.88 | G | N |
| ATOM | 7168 | CA | TYR | G | 379 | −12.888 | 47.621 | 66.998 | 1.00 | 51.30 | G | C |
| ATOM | 7169 | CB | TYR | G | 379 | −12.546 | 49.058 | 66.663 | 1.00 | 53.77 | G | C |
| ATOM | 7170 | CG | TYR | G | 379 | −11.230 | 49.386 | 67.317 | 1.00 | 59.01 | G | C |
| ATOM | 7171 | CD1 | TYR | G | 379 | −10.018 | 49.026 | 66.710 | 1.00 | 60.09 | G | C |
| ATOM | 7172 | CE1 | TYR | G | 379 | −8.800 | 49.210 | 67.363 | 1.00 | 62.35 | G | C |
| ATOM | 7173 | CD2 | TYR | G | 379 | −11.190 | 49.948 | 68.596 | 1.00 | 61.32 | G | C |
| ATOM | 7174 | CE2 | TYR | G | 379 | −9.975 | 50.139 | 69.263 | 1.00 | 64.25 | G | C |
| ATOM | 7175 | CZ | TYR | G | 379 | −8.783 | 49.764 | 68.643 | 1.00 | 64.44 | G | C |
| ATOM | 7176 | OH | TYR | G | 379 | −7.586 | 49.916 | 69.318 | 1.00 | 64.35 | G | O |
| ATOM | 7177 | C | TYR | G | 379 | −14.380 | 47.362 | 67.003 | 1.00 | 47.55 | G | C |
| ATOM | 7178 | O | TYR | G | 379 | −15.176 | 47.943 | 66.254 | 1.00 | 46.89 | G | O |
| ATOM | 7179 | N | ASN | G | 380 | −14.709 | 46.458 | 67.913 | 1.00 | 41.39 | G | N |
| ATOM | 7180 | CA | ASN | G | 380 | −16.029 | 45.923 | 68.145 | 1.00 | 34.70 | G | C |
| ATOM | 7181 | CB | ASN | G | 380 | −15.845 | 44.694 | 69.020 | 1.00 | 35.84 | G | C |
| ATOM | 7182 | CG | ASN | G | 380 | −14.500 | 44.031 | 68.782 | 1.00 | 34.09 | G | C |
| ATOM | 7183 | OD1 | ASN | G | 380 | −14.222 | 43.575 | 67.683 | 1.00 | 32.16 | G | O |
| ATOM | 7184 | ND2 | ASN | G | 380 | −13.657 | 43.996 | 69.803 | 1.00 | 35.70 | G | N |
| ATOM | 7185 | C | ASN | G | 380 | −17.123 | 46.808 | 68.713 | 1.00 | 30.26 | G | C |
| ATOM | 7186 | O | ASN | G | 380 | −16.862 | 47.819 | 69.369 | 1.00 | 26.33 | G | O |
| ATOM | 7187 | N | PRO | G | 381 | −18.382 | 46.427 | 68.452 | 1.00 | 26.47 | G | N |
| ATOM | 7188 | CD | PRO | G | 381 | −18.792 | 45.255 | 67.660 | 1.00 | 24.30 | G | C |
| ATOM | 7189 | CA | PRO | G | 381 | −19.534 | 47.177 | 68.948 | 1.00 | 25.10 | G | C |
| ATOM | 7190 | CB | PRO | G | 381 | −20.733 | 46.364 | 68.459 | 1.00 | 21.99 | G | C |
| ATOM | 7191 | CG | PRO | G | 381 | −20.210 | 45.569 | 67.320 | 1.00 | 23.25 | G | C |
| ATOM | 7192 | C | PRO | G | 381 | −19.462 | 47.237 | 70.476 | 1.00 | 24.19 | G | C |
| ATOM | 7193 | O | PRO | G | 381 | −19.268 | 46.211 | 71.132 | 1.00 | 20.95 | G | O |
| ATOM | 7194 | N | VAL | G | 382 | −19.603 | 48.442 | 71.023 | 1.00 | 23.31 | G | N |
| ATOM | 7195 | CA | VAL | G | 382 | −19.558 | 48.664 | 72.461 | 1.00 | 26.86 | G | C |
| ATOM | 7196 | CB | VAL | G | 382 | −20.879 | 48.174 | 73.148 | 1.00 | 26.19 | G | C |
| ATOM | 7197 | CG1 | VAL | G | 382 | −20.754 | 46.749 | 73.587 | 1.00 | 34.47 | G | C |
| ATOM | 7198 | CG2 | VAL | G | 382 | −21.193 | 49.040 | 74.353 | 1.00 | 28.38 | G | C |
| ATOM | 7199 | C | VAL | G | 382 | −18.332 | 48.003 | 73.099 | 1.00 | 25.63 | G | C |
| ATOM | 7200 | O | VAL | G | 382 | −18.350 | 47.631 | 74.270 | 1.00 | 27.10 | G | O |
| ATOM | 7201 | N | GLY | G | 383 | −17.267 | 47.875 | 72.306 | 1.00 | 25.68 | G | N |
| ATOM | 7202 | CA | GLY | G | 383 | −16.026 | 47.281 | 72.770 | 1.00 | 21.27 | G | C |
| ATOM | 7203 | C | GLY | G | 383 | −16.072 | 45.795 | 73.061 | 1.00 | 21.79 | G | C |
| ATOM | 7204 | O | GLY | G | 383 | −15.125 | 45.261 | 73.633 | 1.00 | 20.64 | G | O |
| ATOM | 7205 | N | ALA | G | 384 | −17.147 | 45.118 | 72.662 | 1.00 | 21.35 | G | N |
| ATOM | 7206 | CA | ALA | G | 384 | −17.285 | 43.686 | 72.935 | 1.00 | 21.78 | G | C |
| ATOM | 7207 | CB | ALA | G | 384 | −18.655 | 43.404 | 73.553 | 1.00 | 16.32 | G | C |
| ATOM | 7208 | C | ALA | G | 384 | −17.068 | 42.800 | 71.709 | 1.00 | 21.89 | G | C |
| ATOM | 7209 | O | ALA | G | 384 | −17.856 | 42.807 | 70.761 | 1.00 | 24.73 | G | O |
| ATOM | 7210 | N | SER | G | 385 | −15.990 | 42.030 | 71.727 | 1.00 | 22.29 | G | N |
| ATOM | 7211 | CA | SER | G | 385 | −15.709 | 41.135 | 70.617 | 1.00 | 23.25 | G | C |
| ATOM | 7212 | CB | SER | G | 385 | −14.363 | 40.433 | 70.837 | 1.00 | 21.88 | G | C |
| ATOM | 7213 | OG | SER | G | 385 | −14.443 | 39.471 | 71.864 | 1.00 | 29.42 | G | O |
| ATOM | 7214 | C | SER | G | 385 | −16.831 | 40.108 | 70.412 | 1.00 | 21.83 | G | C |
| ATOM | 7215 | O | SER | G | 385 | −17.021 | 39.618 | 69.306 | 1.00 | 24.10 | G | O |
| ATOM | 7216 | N | GLU | G | 386 | −17.575 | 39.793 | 71.470 | 1.00 | 23.24 | G | N |
| ATOM | 7217 | CA | GLU | G | 386 | −18.682 | 38.841 | 71.384 | 1.00 | 22.46 | G | C |
| ATOM | 7218 | CB | GLU | G | 386 | −19.314 | 38.604 | 72.758 | 1.00 | 23.14 | G | C |
| ATOM | 7219 | CG | GLU | G | 386 | −18.442 | 37.843 | 73.731 | 1.00 | 26.31 | G | C |
| ATOM | 7220 | CD | GLU | G | 386 | −17.555 | 38.754 | 74.568 | 1.00 | 29.78 | G | C |
| ATOM | 7221 | OE1 | GLU | G | 386 | −16.879 | 38.237 | 75.477 | 1.00 | 31.51 | G | O |
| ATOM | 7222 | OE2 | GLU | G | 386 | −17.520 | 39.983 | 74.324 | 1.00 | 29.73 | G | O |
| ATOM | 7223 | C | GLU | G | 386 | −19.751 | 39.411 | 70.478 | 1.00 | 22.84 | G | C |
| ATOM | 7224 | O | GLU | G | 386 | −20.415 | 38.670 | 69.766 | 1.00 | 23.62 | G | O |
| ATOM | 7225 | N | LEU | G | 387 | −19.918 | 40.733 | 70.523 | 1.00 | 22.01 | G | N |
| ATOM | 7226 | CA | LEU | G | 387 | −20.930 | 41.410 | 69.729 | 1.00 | 20.90 | G | C |
| ATOM | 7227 | CB | LEU | G | 387 | −21.212 | 42.779 | 70.328 | 1.00 | 20.82 | G | C |
| ATOM | 7228 | CG | LEU | G | 387 | −21.857 | 42.698 | 71.719 | 1.00 | 21.87 | G | C |
| ATOM | 7229 | CD1 | LEU | G | 387 | −22.100 | 44.101 | 72.247 | 1.00 | 21.57 | G | C |
| ATOM | 7230 | CD2 | LEU | G | 387 | −23.171 | 41.940 | 71.648 | 1.00 | 23.47 | G | C |
| ATOM | 7231 | C | LEU | G | 387 | −20.530 | 41.518 | 68.263 | 1.00 | 22.38 | G | C |
| ATOM | 7232 | O | LEU | G | 387 | −21.376 | 41.535 | 67.379 | 1.00 | 21.42 | G | O |
| ATOM | 7233 | N | ARG | G | 388 | −19.233 | 41.581 | 68.009 | 1.00 | 21.96 | G | N |
| ATOM | 7234 | CA | ARG | G | 388 | −18.744 | 41.619 | 66.645 | 1.00 | 23.26 | G | C |
| ATOM | 7235 | CB | ARG | G | 388 | −17.257 | 41.974 | 66.641 | 1.00 | 25.03 | G | C |
| ATOM | 7236 | CG | ARG | G | 388 | −16.393 | 41.118 | 65.746 | 1.00 | 29.93 | G | C |
| ATOM | 7237 | CD | ARG | G | 388 | −15.733 | 41.955 | 64.674 | 1.00 | 34.36 | G | C |
| ATOM | 7238 | NE | ARG | G | 388 | −15.646 | 43.373 | 65.041 | 1.00 | 43.25 | G | N |
| ATOM | 7239 | CZ | ARG | G | 388 | −15.630 | 44.385 | 64.166 | 1.00 | 43.30 | G | C |
| ATOM | 7240 | NH1 | ARG | G | 388 | −15.548 | 45.642 | 64.595 | 1.00 | 42.33 | G | N |
| ATOM | 7241 | NH2 | ARG | G | 388 | −15.702 | 44.147 | 62.859 | 1.00 | 43.38 | G | N |
| ATOM | 7242 | C | ARG | G | 388 | −18.977 | 40.219 | 66.053 | 1.00 | 22.16 | G | C |
| ATOM | 7243 | O | ARG | G | 388 | −19.455 | 40.070 | 64.925 | 1.00 | 19.88 | G | O |
| ATOM | 7244 | N | ASP | G | 389 | −18.651 | 39.200 | 66.838 | 1.00 | 18.35 | G | N |
| ATOM | 7245 | CA | ASP | G | 389 | −18.826 | 37.822 | 66.422 | 1.00 | 19.33 | G | C |
| ATOM | 7246 | CB | ASP | G | 389 | −18.344 | 36.900 | 67.531 | 1.00 | 22.76 | G | C |
| ATOM | 7247 | CG | ASP | G | 389 | −16.830 | 36.875 | 67.649 | 1.00 | 28.38 | G | C |
| ATOM | 7248 | OD1 | ASP | G | 389 | −16.319 | 36.364 | 68.671 | 1.00 | 33.91 | G | O |
| ATOM | 7249 | OD2 | ASP | G | 389 | −16.144 | 37.360 | 66.725 | 1.00 | 28.21 | G | O |
| ATOM | 7250 | C | ASP | G | 389 | −20.275 | 37.480 | 66.086 | 1.00 | 18.39 | G | C |
| ATOM | 7251 | O | ASP | G | 389 | −20.550 | 36.755 | 65.128 | 1.00 | 18.19 | G | O |
| ATOM | 7252 | N | LEU | G | 390 | −21.194 | 38.009 | 66.884 | 1.00 | 18.03 | G | N |
| ATOM | 7253 | CA | LEU | G | 390 | −22.617 | 37.754 | 66.705 | 1.00 | 17.75 | G | C |
| ATOM | 7254 | CB | LEU | G | 390 | −23.355 | 38.057 | 68.020 | 1.00 | 13.81 | G | C |
| ATOM | 7255 | CG | LEU | G | 390 | −24.890 | 37.966 | 68.041 | 1.00 | 17.92 | G | C |
| ATOM | 7256 | CD1 | LEU | G | 390 | −25.325 | 36.545 | 67.774 | 1.00 | 18.17 | G | C |
| ATOM | 7257 | CD2 | LEU | G | 390 | −25.414 | 38.431 | 69.377 | 1.00 | 12.31 | G | C |
| ATOM | 7258 | C | LEU | G | 390 | −23.284 | 38.533 | 65.556 | 1.00 | 16.50 | G | C |
| ATOM | 7259 | O | LEU | G | 390 | −24.075 | 37.970 | 64.790 | 1.00 | 16.49 | G | O |
| ATOM | 7260 | N | TYR | G | 391 | −22.957 | 39.814 | 65.428 | 1.00 | 14.61 | G | N |
| ATOM | 7261 | CA | TYR | G | 391 | −23.593 | 40.655 | 64.420 | 1.00 | 14.92 | G | C |
| ATOM | 7262 | CB | TYR | G | 391 | −23.911 | 42.030 | 65.034 | 1.00 | 12.87 | G | C |
| ATOM | 7263 | CG | TYR | G | 391 | −24.968 | 41.997 | 66.119 | 1.00 | 15.32 | G | C |
| ATOM | 7264 | CD1 | TYR | G | 391 | −26.323 | 41.935 | 65.799 | 1.00 | 15.56 | G | C |
| ATOM | 7265 | CE1 | TYR | G | 391 | −27.302 | 41.867 | 66.793 | 1.00 | 14.92 | G | C |
| ATOM | 7266 | CD2 | TYR | G | 391 | −24.611 | 41.995 | 67.477 | 1.00 | 16.66 | G | C |
| ATOM | 7267 | CE2 | TYR | G | 391 | −25.583 | 41.927 | 68.479 | 1.00 | 14.08 | G | C |
| ATOM | 7268 | CZ | TYR | G | 391 | −26.917 | 41.862 | 68.131 | 1.00 | 15.55 | G | C |
| ATOM | 7269 | OH | TYR | G | 391 | −27.865 | 41.789 | 69.123 | 1.00 | 17.73 | G | O |
| ATOM | 7270 | C | TYR | G | 391 | −22.833 | 40.879 | 63.116 | 1.00 | 14.31 | G | C |
| ATOM | 7271 | O | TYR | G | 391 | −23.441 | 41.205 | 62.100 | 1.00 | 13.10 | G | O |
| ATOM | 7272 | N | LEU | G | 392 | −21.516 | 40.706 | 63.142 | 1.00 | 14.63 | G | N |
| ATOM | 7273 | CA | LEU | G | 392 | −20.702 | 40.997 | 61.966 | 1.00 | 15.77 | G | C |
| ATOM | 7274 | CB | LEU | G | 392 | −19.801 | 42.202 | 62.264 | 1.00 | 14.16 | G | C |
| ATOM | 7275 | CG | LEU | G | 392 | −20.498 | 43.430 | 62.855 | 1.00 | 18.18 | G | C |
| ATOM | 7276 | CD1 | LEU | G | 392 | −19.468 | 44.452 | 63.323 | 1.00 | 17.02 | G | C |
| ATOM | 7277 | CD2 | LEU | G | 392 | −21.422 | 44.050 | 61.817 | 1.00 | 16.96 | G | C |
| ATOM | 7278 | C | LEU | G | 392 | −19.853 | 39.872 | 61.395 | 1.00 | 16.13 | G | C |
| ATOM | 7279 | O | LEU | G | 392 | −18.853 | 40.135 | 60.714 | 1.00 | 16.35 | G | O |
| ATOM | 7280 | N | LYS | G | 393 | −20.254 | 38.631 | 61.653 | 1.00 | 16.60 | G | N |
| ATOM | 7281 | CA | LYS | G | 393 | −19.528 | 37.478 | 61.143 | 1.00 | 16.33 | G | C |
| ATOM | 7282 | CB | LYS | G | 393 | −18.817 | 36.750 | 62.269 | 1.00 | 20.49 | G | C |
| ATOM | 7283 | CG | LYS | G | 393 | −17.798 | 37.598 | 62.955 | 1.00 | 24.18 | G | C |
| ATOM | 7284 | CD | LYS | G | 393 | −16.490 | 36.877 | 62.978 | 1.00 | 29.33 | G | C |
| ATOM | 7285 | CE | LYS | G | 393 | −15.347 | 37.842 | 63.182 | 1.00 | 35.37 | G | C |
| ATOM | 7286 | NZ | LYS | G | 393 | −14.448 | 37.323 | 64.255 | 1.00 | 42.52 | G | N |
| ATOM | 7287 | C | LYS | G | 393 | −20.479 | 36.526 | 60.477 | 1.00 | 14.98 | G | C |
| ATOM | 7288 | O | LYS | G | 393 | −21.663 | 36.503 | 60.809 | 1.00 | 12.69 | G | O |
| ATOM | 7289 | N | THR | G | 394 | −19.948 | 35.743 | 59.539 | 1.00 | 15.33 | G | N |
| ATOM | 7290 | CA | THR | G | 394 | −20.748 | 34.770 | 58.802 | 1.00 | 17.49 | G | C |
| ATOM | 7291 | CB | THR | G | 394 | −20.200 | 34.560 | 57.350 | 1.00 | 12.95 | G | C |
| ATOM | 7292 | OG1 | THR | G | 394 | −18.859 | 34.072 | 57.408 | 1.00 | 11.81 | G | O |
| ATOM | 7293 | CG2 | THR | G | 394 | −20.210 | 35.860 | 56.577 | 1.00 | 11.69 | G | C |
| ATOM | 7294 | C | THR | G | 394 | −20.772 | 33.417 | 59.532 | 1.00 | 18.83 | G | C |
| ATOM | 7295 | O | THR | G | 394 | −21.709 | 32.628 | 59.380 | 1.00 | 20.80 | G | O |
| ATOM | 7296 | N | ASP | G | 395 | −19.740 | 33.147 | 60.321 | 1.00 | 19.04 | G | N |
| ATOM | 7297 | CA | ASP | G | 395 | −19.686 | 31.893 | 61.050 | 1.00 | 21.93 | G | C |
| ATOM | 7298 | CB | ASP | G | 395 | −18.406 | 31.142 | 60.715 | 1.00 | 25.06 | G | C |
| ATOM | 7299 | CG | ASP | G | 395 | −18.434 | 29.694 | 61.207 | 1.00 | 33.36 | G | C |
| ATOM | 7300 | OD1 | ASP | G | 395 | −19.550 | 29.123 | 61.360 | 1.00 | 37.17 | G | O |
| ATOM | 7301 | OD2 | ASP | G | 395 | −17.339 | 29.128 | 61.437 | 1.00 | 34.08 | G | O |
| ATOM | 7302 | C | ASP | G | 395 | −19.765 | 32.093 | 62.558 | 1.00 | 22.04 | G | C |
| ATOM | 7303 | O | ASP | G | 395 | −18.884 | 32.698 | 63.161 | 1.00 | 20.92 | G | O |
| ATOM | 7304 | N | ASN | G | 396 | −20.830 | 31.589 | 63.161 | 1.00 | 22.30 | G | N |
| ATOM | 7305 | CA | ASN | G | 396 | −21.009 | 31.708 | 64.591 | 1.00 | 21.67 | G | C |
| ATOM | 7306 | CB | ASN | G | 396 | −21.298 | 33.172 | 64.991 | 1.00 | 18.38 | G | C |
| ATOM | 7307 | CG | ASN | G | 396 | −22.581 | 33.716 | 64.399 | 1.00 | 18.65 | G | C |
| ATOM | 7308 | OD1 | ASN | G | 396 | −22.753 | 34.934 | 64.294 | 1.00 | 23.51 | G | O |
| ATOM | 7309 | ND2 | ASN | G | 396 | −23.488 | 32.834 | 64.019 | 1.00 | 12.69 | G | N |
| ATOM | 7310 | C | ASN | G | 396 | −22.130 | 30.780 | 65.007 | 1.00 | 22.72 | G | C |
| ATOM | 7311 | O | ASN | G | 396 | −22.595 | 29.978 | 64.194 | 1.00 | 21.85 | G | O |
| ATOM | 7312 | N | TYR | G | 397 | −22.563 | 30.891 | 66.262 | 1.00 | 22.07 | G | N |
| ATOM | 7313 | CA | TYR | G | 397 | −23.607 | 30.025 | 66.786 | 1.00 | 21.58 | G | C |
| ATOM | 7314 | CB | TYR | G | 397 | −23.866 | 30.334 | 68.255 | 1.00 | 23.15 | G | C |
| ATOM | 7315 | CG | TYR | G | 397 | −24.711 | 29.279 | 68.907 | 1.00 | 21.67 | G | C |
| ATOM | 7316 | CD1 | TYR | G | 397 | −26.096 | 29.424 | 68.998 | 1.00 | 21.08 | G | C |
| ATOM | 7317 | CE1 | TYR | G | 397 | −26.885 | 28.439 | 69.578 | 1.00 | 23.59 | G | C |
| ATOM | 7318 | CD2 | TYR | G | 397 | −24.128 | 28.122 | 69.415 | 1.00 | 25.46 | G | C |
| ATOM | 7319 | CE2 | TYR | G | 397 | −24.901 | 27.123 | 70.001 | 1.00 | 27.19 | G | C |
| ATOM | 7320 | CZ | TYR | G | 397 | −26.282 | 27.288 | 70.078 | 1.00 | 28.57 | G | C |
| ATOM | 7321 | OH | TYR | G | 397 | −27.060 | 26.297 | 70.640 | 1.00 | 32.58 | G | O |
| ATOM | 7322 | C | TYR | G | 397 | −24.923 | 30.062 | 66.022 | 1.00 | 21.68 | G | C |
| ATOM | 7323 | O | TYR | G | 397 | −25.617 | 29.050 | 65.946 | 1.00 | 23.50 | G | O |
| ATOM | 7324 | N | ILE | G | 398 | −25.291 | 31.215 | 65.475 | 1.00 | 19.67 | G | N |
| ATOM | 7325 | CA | ILE | G | 398 | −26.527 | 31.285 | 64.716 | 1.00 | 18.48 | G | C |
| ATOM | 7326 | CB | ILE | G | 398 | −27.368 | 32.525 | 65.117 | 1.00 | 19.25 | G | C |
| ATOM | 7327 | CG2 | ILE | G | 398 | −27.910 | 32.346 | 66.543 | 1.00 | 16.24 | G | C |
| ATOM | 7328 | CC1 | ILE | G | 398 | −26.520 | 33.790 | 65.038 | 1.00 | 16.94 | G | C |
| ATOM | 7329 | CD1 | ILE | G | 398 | −27.343 | 35.057 | 65.057 | 1.00 | 16.77 | G | C |
| ATOM | 7330 | C | ILE | G | 398 | −26.208 | 31.312 | 63.220 | 1.00 | 19.11 | G | C |
| ATOM | 7331 | O | ILE | G | 398 | −26.969 | 31.840 | 62.415 | 1.00 | 22.30 | G | O |
| ATOM | 7332 | N | ASN | G | 399 | −25.067 | 30.736 | 62.863 | 1.00 | 19.04 | G | N |
| ATOM | 7333 | CA | ASN | G | 399 | −24.613 | 30.654 | 61.479 | 1.00 | 21.50 | G | C |
| ATOM | 7334 | CB | ASN | G | 399 | −25.399 | 29.564 | 60.753 | 1.00 | 23.24 | G | C |
| ATOM | 7335 | CG | ASN | G | 399 | −25.317 | 28.224 | 61.468 | 1.00 | 27.49 | G | C |
| ATOM | 7336 | OD1 | ASN | G | 399 | −24.221 | 27.709 | 61.720 | 1.00 | 30.86 | G | O |
| ATOM | 7337 | ND2 | ASN | G | 399 | −26.472 | 27.658 | 61.809 | 1.00 | 25.32 | G | N |
| ATOM | 7338 | C | ASN | G | 399 | −24.695 | 31.962 | 60.697 | 1.00 | 22.18 | G | C |
| ATOM | 7339 | O | ASN | G | 399 | −25.248 | 32.008 | 59.593 | 1.00 | 23.26 | G | O |
| ATOM | 7340 | N | GLY | G | 400 | −24.145 | 33.021 | 61.281 | 1.00 | 18.48 | G | N |
| ATOM | 7341 | CA | GLY | G | 400 | −24.139 | 34.314 | 60.635 | 1.00 | 16.85 | G | C |
| ATOM | 7342 | C | GLY | G | 400 | −25.467 | 34.891 | 60.199 | 1.00 | 17.20 | G | C |
| ATOM | 7343 | O | GLY | G | 400 | −25.499 | 35.770 | 59.342 | 1.00 | 18.23 | G | O |
| ATOM | 7344 | N | GLU | G | 401 | −26.563 | 34.446 | 60.793 | 1.00 | 16.96 | G | N |
| ATOM | 7345 | CA | GLU | G | 401 | −27.860 | 34.966 | 60.400 | 1.00 | 18.43 | G | C |
| ATOM | 7346 | CB | GLU | G | 401 | −28.968 | 34.217 | 61.133 | 1.00 | 19.95 | G | C |
| ATOM | 7347 | CG | GLU | G | 401 | −30.313 | 34.884 | 60.944 | 1.00 | 28.01 | G | C |
| ATOM | 7348 | CD | GLU | G | 401 | −31.383 | 34.328 | 61.867 | 1.00 | 30.64 | G | C |
| ATOM | 7349 | OE1 | GLU | G | 401 | −31.412 | 33.077 | 62.015 | 1.00 | 28.82 | G | O |
| ATOM | 7350 | OE2 | GLU | G | 401 | −32.178 | 35.139 | 62.429 | 1.00 | 23.15 | G | O |
| ATOM | 7351 | C | GLU | G | 401 | −28.078 | 36.478 | 60.565 | 1.00 | 19.64 | G | C |
| ATOM | 7352 | O | GLU | G | 401 | −28.751 | 37.105 | 59.740 | 1.00 | 22.12 | G | O |
| ATOM | 7353 | N | TYR | G | 402 | −27.530 | 37.069 | 61.622 | 1.00 | 19.33 | G | N |
| ATOM | 7354 | CA | TYR | G | 402 | −27.708 | 38.507 | 61.866 | 1.00 | 17.27 | G | C |
| ATOM | 7355 | CB | TYR | G | 402 | −27.220 | 38.880 | 63.275 | 1.00 | 17.22 | G | C |
| ATOM | 7356 | CG | TYR | G | 402 | −28.170 | 38.490 | 64.391 | 1.00 | 19.72 | G | C |
| ATOM | 7357 | CD1 | TYR | G | 402 | −29.396 | 37.892 | 64.109 | 1.00 | 19.18 | G | C |
| ATOM | 7358 | CE1 | TYR | G | 402 | −30.293 | 37.575 | 65.122 | 1.00 | 20.48 | G | C |
| ATOM | 7359 | CD2 | TYR | G | 402 | −27.859 | 38.757 | 65.727 | 1.00 | 16.53 | G | C |
| ATOM | 7360 | CE2 | TYR | G | 402 | −28.751 | 38.443 | 66.747 | 1.00 | 19.19 | G | C |
| ATOM | 7361 | CZ | TYR | G | 402 | −29.968 | 37.856 | 66.435 | 1.00 | 19.42 | G | C |
| ATOM | 7362 | OH | TYR | G | 402 | −30.890 | 37.588 | 67.415 | 1.00 | 19.79 | G | O |
| ATOM | 7363 | C | TYR | G | 402 | −26.957 | 39.343 | 60.840 | 1.00 | 15.97 | G | C |
| ATOM | 7364 | O | TYR | G | 402 | −27.462 | 40.352 | 60.356 | 1.00 | 14.98 | G | O |
| ATOM | 7365 | N | PHE | G | 403 | −25.736 | 38.923 | 60.537 | 1.00 | 15.00 | G | N |
| ATOM | 7366 | CA | PHE | G | 403 | −24.901 | 39.600 | 59.557 | 1.00 | 15.29 | G | C |
| ATOM | 7367 | CB | PHE | G | 403 | −23.551 | 38.896 | 59.477 | 1.00 | 14.54 | G | C |
| ATOM | 7368 | CG | PHE | G | 403 | −22.542 | 39.610 | 58.632 | 1.00 | 15.84 | G | C |
| ATOM | 7369 | CD1 | PHE | G | 403 | −22.548 | 40.998 | 58.541 | 1.00 | 15.77 | G | C |
| ATOM | 7370 | CD2 | PHE | G | 403 | −21.561 | 38.890 | 57.944 | 1.00 | 14.86 | G | C |
| ATOM | 7371 | CE1 | PHE | G | 403 | −21.590 | 41.666 | 57.777 | 1.00 | 17.99 | G | C |
| ATOM | 7372 | CE2 | PHE | G | 403 | −20.600 | 39.542 | 57.179 | 1.00 | 14.17 | G | C |
| ATOM | 7373 | CZ | PHE | G | 403 | −20.612 | 40.933 | 57.093 | 1.00 | 16.70 | G | C |
| ATOM | 7374 | C | PHE | G | 403 | −25.598 | 39.557 | 58.201 | 1.00 | 15.67 | G | C |
| ATOM | 7375 | O | PHE | G | 403 | −25.639 | 40.544 | 57.478 | 1.00 | 16.88 | G | O |
| ATOM | 7376 | N | ALA | G | 404 | −26.161 | 38.402 | 57.871 | 1.00 | 16.61 | G | N |
| ATOM | 7377 | CA | ALA | G | 404 | −26.879 | 38.225 | 56.617 | 1.00 | 15.15 | G | C |
| ATOM | 7378 | CB | ALA | G | 404 | −27.391 | 36.794 | 56.498 | 1.00 | 13.06 | G | C |
| ATOM | 7379 | C | ALA | G | 404 | −28.039 | 39.191 | 56.550 | 1.00 | 16.30 | G | C |
| ATOM | 7380 | O | ALA | G | 404 | −28.232 | 39.867 | 55.544 | 1.00 | 17.53 | G | O |
| ATOM | 7381 | N | THR | G | 405 | −28.813 | 39.260 | 57.627 | 1.00 | 16.86 | G | N |
| ATOM | 7382 | CA | THR | G | 405 | −29.975 | 40.141 | 57.681 | 1.00 | 17.22 | G | C |
| ATOM | 7383 | CB | THR | G | 405 | −30.773 | 39.913 | 58.979 | 1.00 | 16.81 | G | C |
| ATOM | 7384 | OG1 | THR | G | 405 | −31.130 | 38.524 | 59.076 | 1.00 | 18.90 | G | O |
| ATOM | 7385 | CG2 | THR | G | 405 | −32.024 | 40.753 | 58.982 | 1.00 | 11.45 | G | C |
| ATOM | 7386 | C | THR | G | 405 | −29.618 | 41.624 | 57.563 | 1.00 | 18.65 | G | C |
| ATOM | 7387 | O | THR | G | 405 | −30.316 | 42.390 | 56.888 | 1.00 | 18.73 | G | O |
| ATOM | 7388 | N | ILE | G | 406 | −28.543 | 42.035 | 58.227 | 1.00 | 18.69 | G | N |
| ATOM | 7389 | CA | ILE | G | 406 | −28.112 | 43.428 | 58.157 | 1.00 | 19.02 | G | C |
| ATOM | 7390 | CB | ILE | G | 406 | −26.886 | 43.713 | 59.075 | 1.00 | 20.44 | G | C |
| ATOM | 7391 | CG2 | ILE | G | 406 | −26.462 | 45.181 | 58.936 | 1.00 | 18.98 | G | C |
| ATOM | 7392 | CG1 | ILE | G | 406 | −27.250 | 43.455 | 60.540 | 1.00 | 22.81 | G | C |
| ATOM | 7393 | CD1 | ILE | G | 406 | −26.068 | 43.541 | 61.508 | 1.00 | 18.20 | G | C |
| ATOM | 7394 | C | ILE | G | 406 | −27.706 | 43.735 | 56.710 | 1.00 | 17.64 | G | C |
| ATOM | 7395 | O | ILE | G | 406 | −28.083 | 44.766 | 56.159 | 1.00 | 15.45 | G | O |
| ATOM | 7396 | N | ILE | G | 407 | −26.938 | 42.826 | 56.108 | 1.00 | 17.82 | G | N |
| ATOM | 7397 | CA | ILE | G | 407 | −26.472 | 42.979 | 54.726 | 1.00 | 16.83 | G | C |
| ATOM | 7398 | CB | ILE | G | 407 | −25.588 | 41.811 | 54.328 | 1.00 | 15.47 | G | C |
| ATOM | 7399 | CG2 | ILE | G | 407 | −25.666 | 41.565 | 52.830 | 1.00 | 18.64 | G | C |
| ATOM | 7400 | CG1 | ILE | G | 407 | −24.152 | 42.122 | 54.709 | 1.00 | 17.04 | G | C |
| ATOM | 7401 | CD1 | ILE | G | 407 | −23.302 | 40.885 | 54.800 | 1.00 | 21.20 | G | C |
| ATOM | 7402 | C | ILE | G | 407 | −27.609 | 43.100 | 53.700 | 1.00 | 17.79 | G | C |
| ATOM | 7403 | O | ILE | G | 407 | −27.533 | 43.914 | 52.777 | 1.00 | 17.82 | G | O |
| ATOM | 7404 | N | LYS | G | 408 | −28.664 | 42.308 | 53.868 | 1.00 | 16.72 | G | N |
| ATOM | 7405 | CA | LYS | G | 408 | −29.776 | 42.358 | 52.940 | 1.00 | 16.53 | G | C |
| ATOM | 7406 | CB | LYS | G | 408 | −30.704 | 41.167 | 53.154 | 1.00 | 17.72 | G | C |
| ATOM | 7407 | CG | LYS | G | 408 | −30.251 | 39.924 | 52.403 | 1.00 | 18.65 | G | C |
| ATOM | 7408 | CD | LYS | G | 408 | −30.205 | 38.737 | 53.325 | 1.00 | 23.68 | G | C |
| ATOM | 7409 | CE | LYS | G | 408 | −31.594 | 38.164 | 53.490 | 1.00 | 26.73 | G | C |
| ATOM | 7410 | NZ | LYS | G | 408 | −32.274 | 38.129 | 52.157 | 1.00 | 34.76 | G | N |
| ATOM | 7411 | C | LYS | G | 408 | −30.528 | 43.659 | 53.097 | 1.00 | 19.17 | G | C |
| ATOM | 7412 | O | LYS | G | 408 | −31.149 | 44.158 | 52.138 | 1.00 | 17.25 | G | O |
| ATOM | 7413 | N | GLU | G | 409 | −30.470 | 44.218 | 54.304 | 1.00 | 16.98 | G | N |
| ATOM | 7414 | CA | GLU | G | 409 | −31.123 | 45.497 | 54.555 | 1.00 | 15.72 | G | C |
| ATOM | 7415 | CB | GLU | G | 409 | −31.187 | 45.781 | 56.058 | 1.00 | 17.17 | G | C |
| ATOM | 7416 | CG | GLU | G | 409 | −32.051 | 44.777 | 56.824 | 1.00 | 20.84 | G | C |
| ATOM | 7417 | CD | GLU | G | 409 | −32.253 | 45.143 | 58.295 | 1.00 | 23.75 | G | C |
| ATOM | 7418 | OE1 | GLU | G | 409 | −31.403 | 45.861 | 58.874 | 1.00 | 20.53 | G | O |
| ATOM | 7419 | OE2 | GLU | G | 409 | −33.272 | 44.701 | 58.865 | 1.00 | 23.79 | G | O |
| ATOM | 7420 | C | GLU | G | 409 | −30.332 | 46.592 | 53.828 | 1.00 | 13.40 | G | C |
| ATOM | 7421 | O | GLU | G | 409 | −30.910 | 47.517 | 53.282 | 1.00 | 13.40 | G | O |
| ATOM | 7422 | N | VAL | G | 410 | −29.006 | 46.481 | 53.828 | 1.00 | 14.12 | G | N |
| ATOM | 7423 | CA | VAL | G | 410 | −28.158 | 47.447 | 53.138 | 1.00 | 13.95 | G | C |
| ATOM | 7424 | CB | VAL | G | 410 | −26.662 | 47.134 | 53.382 | 1.00 | 13.97 | G | C |
| ATOM | 7425 | CG1 | VAL | G | 410 | −25.786 | 48.068 | 52.537 | 1.00 | 13.40 | G | C |
| ATOM | 7426 | CG2 | VAL | G | 410 | −26.326 | 47.270 | 54.879 | 1.00 | 9.06 | G | C |
| ATOM | 7427 | C | VAL | G | 410 | −28.466 | 47.347 | 51.624 | 1.00 | 18.80 | G | C |
| ATOM | 7428 | O | VAL | G | 410 | −28.653 | 48.364 | 50.945 | 1.00 | 15.42 | G | O |
| ATOM | 7429 | N | GLY | G | 411 | −28.540 | 46.110 | 51.117 | 1.00 | 19.59 | G | N |
| ATOM | 7430 | CA | GLY | G | 411 | −28.832 | 45.891 | 49.712 | 1.00 | 17.41 | G | C |
| ATOM | 7431 | C | GLY | G | 411 | −30.159 | 46.500 | 49.293 | 1.00 | 18.97 | G | C |
| ATOM | 7432 | O | GLY | G | 411 | −30.267 | 47.105 | 48.219 | 1.00 | 21.23 | G | O |
| ATOM | 7433 | N | ALA | G | 412 | −31.178 | 46.359 | 50.131 | 1.00 | 16.44 | G | N |
| ATOM | 7434 | CA | ALA | G | 412 | −32.487 | 46.907 | 49.803 | 1.00 | 16.98 | G | C |
| ATOM | 7435 | CB | ALA | G | 412 | −33.531 | 46.372 | 50.759 | 1.00 | 14.09 | G | C |
| ATOM | 7436 | C | ALA | G | 412 | −32.489 | 48.430 | 49.820 | 1.00 | 17.78 | G | C |
| ATOM | 7437 | O | ALA | G | 412 | −33.314 | 49.067 | 49.163 | 1.00 | 16.07 | G | O |
| ATOM | 7438 | N | ASP | G | 413 | −31.576 | 49.024 | 50.578 | 1.00 | 17.89 | G | N |
| ATOM | 7439 | CA | ASP | G | 413 | −31.511 | 50.481 | 50.634 | 1.00 | 19.37 | G | C |
| ATOM | 7440 | CB | ASP | G | 413 | −30.616 | 50.936 | 51.790 | 1.00 | 22.85 | G | C |
| ATOM | 7441 | CG | ASP | G | 413 | −31.352 | 50.971 | 53.127 | 1.00 | 26.74 | G | C |
| ATOM | 7442 | OD1 | ASP | G | 413 | −30.680 | 50.977 | 54.187 | 1.00 | 30.37 | G | O |
| ATOM | 7443 | OD2 | ASP | G | 413 | −32.599 | 50.992 | 53.115 | 1.00 | 26.25 | G | O |
| ATOM | 7444 | C | ASP | G | 413 | −30.918 | 50.949 | 49.314 | 1.00 | 19.47 | G | C |
| ATOM | 7445 | O | ASP | G | 413 | −31.300 | 51.986 | 48.775 | 1.00 | 18.99 | G | O |
| ATOM | 7446 | N | LEU | G | 414 | −29.962 | 50.167 | 48.822 | 1.00 | 17.88 | G | N |
| ATOM | 7447 | CA | LEU | G | 414 | −29.276 | 50.414 | 47.560 | 1.00 | 17.06 | G | C |
| ATOM | 7448 | CB | LEU | G | 414 | −28.189 | 49.350 | 47.380 | 1.00 | 15.58 | G | C |
| ATOM | 7449 | CG | LEU | G | 414 | −26.711 | 49.723 | 47.498 | 1.00 | 19.17 | G | C |
| ATOM | 7450 | CD1 | LEU | G | 414 | −26.546 | 50.958 | 48.307 | 1.00 | 15.31 | G | C |
| ATOM | 7451 | CD2 | LEU | G | 414 | −25.943 | 48.575 | 48.088 | 1.00 | 15.04 | G | C |
| ATOM | 7452 | C | LEU | G | 414 | −30.307 | 50.316 | 46.413 | 1.00 | 16.92 | G | C |
| ATOM | 7453 | O | LEU | G | 414 | −30.399 | 51.189 | 45.548 | 1.00 | 13.55 | G | O |
| ATOM | 7454 | N | VAL | G | 415 | −31.084 | 49.241 | 46.421 | 1.00 | 16.16 | G | N |
| ATOM | 7455 | CA | VAL | G | 415 | −32.101 | 49.042 | 45.403 | 1.00 | 18.88 | G | C |
| ATOM | 7456 | CB | VAL | G | 415 | −32.854 | 47.721 | 45.626 | 1.00 | 18.88 | G | C |
| ATOM | 7457 | CG1 | VAL | G | 415 | −34.088 | 47.657 | 44.735 | 1.00 | 17.53 | G | C |
| ATOM | 7458 | CG2 | VAL | G | 415 | −31.926 | 46.556 | 45.323 | 1.00 | 16.33 | G | C |
| ATOM | 7459 | C | VAL | G | 415 | −33.098 | 50.188 | 45.370 | 1.00 | 19.52 | G | C |
| ATOM | 7460 | O | VAL | G | 415 | −33.597 | 50.554 | 44.320 | 1.00 | 20.87 | G | O |
| ATOM | 7461 | N | ASP | G | 416 | −33.395 | 50.761 | 46.520 | 1.00 | 21.86 | G | N |
| ATOM | 7462 | CA | ASP | G | 416 | −34.335 | 51.871 | 46.572 | 1.00 | 23.70 | G | C |
| ATOM | 7463 | CB | ASP | G | 416 | −34.722 | 52.205 | 48.013 | 1.00 | 29.09 | G | C |
| ATOM | 7464 | CG | ASP | G | 416 | −35.803 | 51.297 | 48.552 | 1.00 | 41.01 | G | C |
| ATOM | 7465 | OD1 | ASP | G | 416 | −35.910 | 51.205 | 49.796 | 1.00 | 49.83 | G | O |
| ATOM | 7466 | OD2 | ASP | G | 416 | −36.544 | 50.671 | 47.748 | 1.00 | 44.59 | G | O |
| ATOM | 7467 | C | ASP | G | 416 | −33.731 | 53.112 | 45.952 | 1.00 | 21.75 | G | C |
| ATOM | 7468 | O | ASP | G | 416 | −34.428 | 53.882 | 45.310 | 1.00 | 22.54 | G | O |
| ATOM | 7469 | N | ALA | G | 417 | −32.437 | 53.315 | 46.166 | 1.00 | 20.27 | G | N |
| ATOM | 7470 | CA | ALA | G | 417 | −31.752 | 54.487 | 45.633 | 1.00 | 20.21 | G | C |
| ATOM | 7471 | CB | ALA | G | 417 | −30.459 | 54.725 | 46.400 | 1.00 | 21.43 | G | C |
| ATOM | 7472 | C | ALA | G | 417 | −31.465 | 54.306 | 44.149 | 1.00 | 19.14 | G | C |
| ATOM | 7473 | O | ALA | G | 417 | −31.172 | 55.269 | 43.432 | 1.00 | 18.56 | G | O |
| ATOM | 7474 | N | LYS | G | 418 | −31.520 | 53.050 | 43.715 | 1.00 | 18.35 | G | N |
| ATOM | 7475 | CA | LYS | G | 418 | −31.325 | 52.662 | 42.321 | 1.00 | 16.35 | G | C |
| ATOM | 7476 | CB | LYS | G | 418 | −32.422 | 53.300 | 41.455 | 1.00 | 17.88 | G | C |
| ATOM | 7477 | CG | LYS | G | 418 | −32.261 | 53.057 | 39.948 | 1.00 | 19.11 | G | C |
| ATOM | 7478 | CD | LYS | G | 418 | −33.470 | 53.570 | 39.161 | 1.00 | 21.50 | G | C |
| ATOM | 7479 | CE | LYS | G | 418 | −33.427 | 53.109 | 37.703 | 1.00 | 23.86 | G | C |
| ATOM | 7480 | NZ | LYS | G | 418 | −34.319 | 53.943 | 36.842 | 1.00 | 25.91 | G | N |
| ATOM | 7481 | C | LYS | G | 418 | −29.990 | 52.887 | 41.619 | 1.00 | 15.24 | G | C |
| ATOM | 7482 | O | LYS | G | 418 | −29.467 | 51.969 | 40.990 | 1.00 | 13.46 | G | O |
| ATOM | 7483 | N | TYR | G | 419 | −29.434 | 54.087 | 41.709 | 1.00 | 12.83 | G | N |
| ATOM | 7484 | CA | TYR | G | 419 | −28.206 | 54.370 | 40.969 | 1.00 | 15.22 | G | C |
| ATOM | 7485 | CB | TYR | G | 419 | −28.223 | 55.834 | 40.519 | 1.00 | 14.15 | G | C |
| ATOM | 7486 | CG | TYR | G | 419 | −29.469 | 56.139 | 39.714 | 1.00 | 16.69 | G | C |
| ATOM | 7487 | CD1 | TYR | G | 419 | −29.614 | 55.651 | 38.418 | 1.00 | 17.41 | G | C |
| ATOM | 7488 | CE1 | TYR | G | 419 | −30.793 | 55.833 | 37.705 | 1.00 | 19.36 | G | C |
| ATOM | 7489 | CD2 | TYR | G | 419 | −30.541 | 56.831 | 40.277 | 1.00 | 15.03 | G | C |
| ATOM | 7490 | CE2 | TYR | G | 419 | −31.729 | 57.019 | 39.571 | 1.00 | 16.13 | G | C |
| ATOM | 7491 | CZ | TYR | G | 419 | −31.847 | 56.515 | 38.287 | 1.00 | 20.65 | G | C |
| ATOM | 7492 | OH | TYR | G | 419 | −33.018 | 56.677 | 37.587 | 1.00 | 24.67 | G | O |
| ATOM | 7493 | C | TYR | G | 419 | −26.860 | 54.015 | 41.570 | 1.00 | 14.55 | G | C |
| ATOM | 7494 | O | TYR | G | 419 | −25.852 | 54.014 | 40.858 | 1.00 | 15.92 | G | O |
| ATOM | 7495 | N | GLN | G | 420 | −26.838 | 53.691 | 42.857 | 1.00 | 13.12 | G | N |
| ATOM | 7496 | CA | GLN | G | 420 | −25.596 | 53.317 | 43.519 | 1.00 | 12.90 | G | C |
| ATOM | 7497 | CB | GLN | G | 420 | −25.488 | 54.011 | 44.883 | 1.00 | 17.42 | G | C |
| ATOM | 7498 | CG | GLN | G | 420 | −25.039 | 55.474 | 44.796 | 1.00 | 19.34 | G | C |
| ATOM | 7499 | CD | GLN | G | 420 | −26.111 | 56.355 | 44.193 | 1.00 | 25.46 | G | C |
| ATOM | 7500 | OE1 | GLN | G | 420 | −25.989 | 56.820 | 43.053 | 1.00 | 26.20 | G | O |
| ATOM | 7501 | NE2 | GLN | G | 420 | −27.180 | 56.586 | 44.954 | 1.00 | 24.18 | G | N |
| ATOM | 7502 | C | GLN | G | 420 | −25.489 | 51.807 | 43.687 | 1.00 | 10.80 | G | C |
| ATOM | 7503 | O | GLN | G | 420 | −26.458 | 51.135 | 44.022 | 1.00 | 12.36 | G | O |
| ATOM | 7504 | N | HIS | G | 421 | −24.291 | 51.289 | 43.443 | 1.00 | 10.28 | G | N |
| ATOM | 7505 | CA | HIS | G | 421 | −23.999 | 49.864 | 43.546 | 1.00 | 9.97 | G | C |
| ATOM | 7506 | CB | HIS | G | 421 | −23.679 | 49.290 | 42.148 | 1.00 | 10.86 | G | C |
| ATOM | 7507 | CG | HIS | G | 421 | −24.839 | 49.333 | 41.194 | 1.00 | 10.81 | G | C |
| ATOM | 7508 | CD2 | HIS | G | 421 | −25.436 | 50.372 | 40.558 | 1.00 | 7.23 | G | C |
| ATOM | 7509 | ND1 | HIS | G | 421 | −25.535 | 48.204 | 40.818 | 1.00 | 7.54 | G | N |
| ATOM | 7510 | CE1 | HIS | G | 421 | −26.509 | 48.545 | 39.992 | 1.00 | 9.40 | G | C |
| ATOM | 7511 | NE2 | HIS | G | 421 | −26.470 | 49.853 | 39.817 | 1.00 | 9.39 | G | N |
| ATOM | 7512 | C | HIS | G | 421 | −22.788 | 49.694 | 44.460 | 1.00 | 9.62 | G | C |
| ATOM | 7513 | O | HIS | G | 421 | −22.080 | 50.663 | 44.758 | 1.00 | 7.25 | G | O |
| ATOM | 7514 | N | ALA | G | 422 | −22.532 | 48.465 | 44.887 | 1.00 | 10.00 | G | N |
| ATOM | 7515 | CA | ALA | G | 422 | −21.397 | 48.208 | 45.768 | 1.00 | 11.70 | G | C |
| ATOM | 7516 | CB | ALA | G | 422 | −21.852 | 48.303 | 47.251 | 1.00 | 7.67 | G | C |
| ATOM | 7517 | C | ALA | G | 422 | −20.772 | 46.838 | 45.485 | 1.00 | 12.84 | G | C |
| ATOM | 7518 | O | ALA | G | 422 | −21.453 | 45.923 | 44.993 | 1.00 | 12.43 | G | O |
| ATOM | 7519 | N | GLU | G | 423 | −19.480 | 46.707 | 45.796 | 1.00 | 11.07 | G | N |
| ATOM | 7520 | CA | GLU | G | 423 | −18.744 | 45.463 | 45.594 | 1.00 | 12.94 | G | C |
| ATOM | 7521 | CB | GLU | G | 423 | −17.587 | 45.689 | 44.610 | 1.00 | 14.52 | G | C |
| ATOM | 7522 | CG | GLU | G | 423 | −17.967 | 46.318 | 43.277 | 1.00 | 12.27 | G | C |
| ATOM | 7523 | CD | GLU | G | 423 | −16.808 | 46.258 | 42.315 | 1.00 | 13.32 | G | C |
| ATOM | 7524 | OE1 | GLU | G | 423 | −16.643 | 45.231 | 41.610 | 1.00 | 16.70 | G | O |
| ATOM | 7525 | OE2 | GLU | G | 423 | −16.033 | 47.227 | 42.281 | 1.00 | 14.74 | G | O |
| ATOM | 7526 | C | GLU | G | 423 | −18.167 | 44.961 | 46.923 | 1.00 | 13.42 | G | C |
| ATOM | 7527 | O | GLU | G | 423 | −16.946 | 44.869 | 47.089 | 1.00 | 17.50 | G | O |
| ATOM | 7528 | N | PRO | G | 424 | −19.033 | 44.590 | 47.875 | 1.00 | 12.62 | G | N |
| ATOM | 7529 | CD | PRO | G | 424 | −20.507 | 44.571 | 47.804 | 1.00 | 8.59 | G | C |
| ATOM | 7530 | CA | PRO | G | 424 | −18.519 | 44.116 | 49.171 | 1.00 | 11.44 | G | C |
| ATOM | 7531 | CB | PRO | G | 424 | −19.788 | 43.857 | 49.993 | 1.00 | 12.60 | G | C |
| ATOM | 7532 | CG | PRO | G | 424 | −20.895 | 43.705 | 48.966 | 1.00 | 11.88 | G | C |
| ATOM | 7533 | C | PRO | G | 424 | −17.578 | 42.908 | 49.169 | 1.00 | 11.55 | G | C |
| ATOM | 7534 | O | PRO | G | 424 | −17.755 | 41.936 | 48.424 | 1.00 | 10.02 | G | O |
| ATOM | 7535 | N | ARG | G | 425 | −16.585 | 42.976 | 50.045 | 1.00 | 11.84 | G | N |
| ATOM | 7536 | CA | ARG | G | 425 | −15.613 | 41.908 | 50.207 | 1.00 | 11.34 | G | C |
| ATOM | 7537 | CB | ARG | G | 425 | −14.207 | 42.527 | 50.355 | 1.00 | 13.85 | G | C |
| ATOM | 7538 | CG | ARG | G | 425 | −13.342 | 42.418 | 49.085 | 1.00 | 17.08 | G | C |
| ATOM | 7539 | CD | ARG | G | 425 | −12.816 | 43.756 | 48.538 | 1.00 | 17.36 | G | C |
| ATOM | 7540 | NE | ARG | G | 425 | −13.820 | 44.489 | 47.786 | 1.00 | 15.85 | G | N |
| ATOM | 7541 | CZ | ARG | G | 425 | −13.592 | 45.355 | 46.788 | 1.00 | 16.38 | G | C |
| ATOM | 7542 | NH1 | ARG | G | 425 | −12.367 | 45.656 | 46.352 | 1.00 | 8.24 | G | N |
| ATOM | 7543 | NH2 | ARG | G | 425 | −14.630 | 45.987 | 46.260 | 1.00 | 12.86 | G | N |
| ATOM | 7544 | C | ARG | G | 425 | −15.981 | 41.037 | 51.434 | 1.00 | 13.50 | G | C |
| ATOM | 7545 | O | ARG | G | 425 | −16.225 | 41.556 | 52.528 | 1.00 | 12.11 | G | O |
| ATOM | 7546 | N | LEU | G | 426 | −16.052 | 39.720 | 51.214 | 1.00 | 13.31 | G | N |
| ATOM | 7547 | CA | LEU | G | 426 | −16.363 | 38.721 | 52.236 | 1.00 | 11.86 | G | C |
| ATOM | 7548 | CB | LEU | G | 426 | −17.384 | 37.699 | 51.718 | 1.00 | 11.91 | G | C |
| ATOM | 7549 | CG | LEU | G | 426 | −18.846 | 38.110 | 51.513 | 1.00 | 12.83 | G | C |
| ATOM | 7550 | CD1 | LEU | G | 426 | −19.574 | 36.984 | 50.791 | 1.00 | 11.73 | G | C |
| ATOM | 7551 | CD2 | LEU | G | 426 | −19.520 | 38.389 | 52.864 | 1.00 | 13.04 | G | C |
| ATOM | 7552 | C | LEU | G | 426 | −15.046 | 38.008 | 52.529 | 1.00 | 14.75 | G | C |
| ATOM | 7553 | O | LEU | G | 426 | −14.203 | 37.855 | 51.641 | 1.00 | 15.70 | G | O |
| ATOM | 7554 | N | SER | G | 427 | −14.865 | 37.567 | 53.770 | 1.00 | 13.83 | G | N |
| ATOM | 7555 | CA | SER | G | 427 | −13.618 | 36.916 | 54.147 | 1.00 | 14.94 | G | C |
| ATOM | 7556 | CB | SER | G | 427 | −13.249 | 37.285 | 55.597 | 1.00 | 12.30 | G | C |
| ATOM | 7557 | OG | SER | G | 427 | −13.027 | 38.673 | 55.743 | 1.00 | 15.26 | G | O |
| ATOM | 7558 | C | SER | G | 427 | −13.536 | 35.402 | 54.037 | 1.00 | 12.73 | G | C |
| ATOM | 7559 | O | SER | G | 427 | −14.462 | 34.691 | 54.391 | 1.00 | 16.19 | G | O |
| ATOM | 7560 | N | ILE | G | 428 | −12.395 | 34.938 | 53.547 | 1.00 | 14.15 | G | N |
| ATOM | 7561 | CA | ILE | G | 428 | −12.057 | 33.525 | 53.484 | 1.00 | 16.35 | G | C |
| ATOM | 7562 | CB | ILE | G | 428 | −12.012 | 32.985 | 52.042 | 1.00 | 15.00 | G | C |
| ATOM | 7563 | CG2 | ILE | G | 428 | −11.133 | 31.726 | 51.980 | 1.00 | 14.12 | G | C |
| ATOM | 7564 | CG1 | ILE | G | 428 | −13.440 | 32.661 | 51.569 | 1.00 | 13.03 | G | C |
| ATOM | 7565 | CD1 | ILE | G | 428 | −14.069 | 31.409 | 52.218 | 1.00 | 8.61 | G | C |
| ATOM | 7566 | C | ILE | G | 428 | −10.647 | 33.645 | 54.080 | 1.00 | 17.47 | G | C |
| ATOM | 7567 | O | ILE | G | 428 | −9.804 | 34.349 | 53.531 | 1.00 | 18.14 | G | O |
| ATOM | 7568 | N | TYR | G | 429 | −10.402 | 32.995 | 55.218 | 1.00 | 19.66 | G | N |
| ATOM | 7569 | CA | TYR | G | 429 | −9.112 | 33.114 | 55.909 | 1.00 | 20.01 | G | C |
| ATOM | 7570 | CB | TYR | G | 429 | −9.343 | 33.089 | 57.422 | 1.00 | 21.71 | G | C |
| ATOM | 7571 | CG | TYR | G | 429 | −10.257 | 34.190 | 57.923 | 1.00 | 19.56 | G | C |
| ATOM | 7572 | CD1 | TYR | G | 429 | −11.631 | 33.995 | 58.004 | 1.00 | 18.40 | G | C |
| ATOM | 7573 | CE1 | TYR | G | 429 | −12.474 | 34.990 | 58.474 | 1.00 | 19.60 | G | C |
| ATOM | 7574 | CD2 | TYR | G | 429 | −9.741 | 35.415 | 58.326 | 1.00 | 18.55 | G | C |
| ATOM | 7575 | CE2 | TYR | G | 429 | −10.578 | 36.424 | 58.801 | 1.00 | 19.52 | G | C |
| ATOM | 7576 | CZ | TYR | G | 429 | −11.938 | 36.204 | 58.872 | 1.00 | 22.23 | G | C |
| ATOM | 7577 | OH | TYR | G | 429 | −12.769 | 37.203 | 59.337 | 1.00 | 25.90 | G | O |
| ATOM | 7578 | C | TYR | G | 429 | −7.992 | 32.137 | 55.595 | 1.00 | 20.91 | G | C |
| ATOM | 7579 | O | TYR | G | 429 | −6.824 | 32.437 | 55.836 | 1.00 | 21.25 | G | O |
| ATOM | 7580 | N | GLY | G | 430 | −8.330 | 30.965 | 55.081 | 1.00 | 20.82 | G | N |
| ATOM | 7581 | CA | GLY | G | 430 | −7.289 | 30.000 | 54.790 | 1.00 | 22.98 | G | C |
| ATOM | 7582 | C | GLY | G | 430 | −6.941 | 29.286 | 56.084 | 1.00 | 23.35 | G | C |
| ATOM | 7583 | O | GLY | G | 430 | −5.939 | 28.574 | 56.171 | 1.00 | 23.06 | G | O |
| ATOM | 7584 | N | ARG | G | 431 | −7.781 | 29.489 | 57.094 | 1.00 | 22.76 | G | N |
| ATOM | 7585 | CA | ARG | G | 431 | −7.590 | 28.869 | 58.400 | 1.00 | 25.58 | G | C |
| ATOM | 7586 | CB | ARG | G | 431 | −8.408 | 29.613 | 59.456 | 1.00 | 28.08 | G | C |
| ATOM | 7587 | CG | ARG | G | 431 | −8.112 | 29.189 | 60.896 | 1.00 | 34.22 | G | C |
| ATOM | 7588 | CD | ARG | G | 431 | −9.277 | 29.516 | 61.834 | 1.00 | 39.13 | G | C |
| ATOM | 7589 | NE | ARG | G | 431 | −10.580 | 29.222 | 61.219 | 1.00 | 45.99 | G | N |
| ATOM | 7590 | CZ | ARG | G | 431 | −11.431 | 30.147 | 60.759 | 1.00 | 46.02 | G | C |
| ATOM | 7591 | NH1 | ARG | G | 431 | −11.120 | 31.443 | 60.840 | 1.00 | 43.80 | G | N |
| ATOM | 7592 | NH2 | ARG | G | 431 | −12.595 | 29.779 | 60.218 | 1.00 | 43.72 | G | N |
| ATOM | 7593 | C | ARG | G | 431 | −8.029 | 27.409 | 58.357 | 1.00 | 25.13 | G | C |
| ATOM | 7594 | O | ARG | G | 431 | −7.375 | 26.525 | 58.901 | 1.00 | 24.23 | G | O |
| ATOM | 7595 | N | SER | G | 432 | −9.145 | 27.158 | 57.694 | 1.00 | 26.14 | G | N |
| ATOM | 7596 | CA | SER | G | 432 | −9.655 | 25.807 | 57.583 | 1.00 | 27.30 | G | C |
| ATOM | 7597 | CB | SER | G | 432 | −10.772 | 25.601 | 58.597 | 1.00 | 28.33 | G | C |
| ATOM | 7598 | OG | SER | G | 432 | −11.682 | 24.630 | 58.112 | 1.00 | 33.36 | G | O |
| ATOM | 7599 | C | SER | G | 432 | −10.183 | 25.523 | 56.179 | 1.00 | 27.76 | G | C |
| ATOM | 7600 | O | SER | G | 432 | −10.649 | 26.420 | 55.481 | 1.00 | 28.43 | G | O |
| ATOM | 7601 | N | PRO | G | 433 | −10.112 | 24.262 | 55.739 | 1.00 | 29.62 | G | N |
| ATOM | 7602 | CD | PRO | G | 433 | −9.540 | 23.090 | 56.430 | 1.00 | 29.01 | G | C |
| ATOM | 7603 | CA | PRO | G | 433 | −10.609 | 23.937 | 54.394 | 1.00 | 29.62 | G | C |
| ATOM | 7604 | CB | PRO | G | 433 | −10.067 | 22.536 | 54.135 | 1.00 | 30.19 | G | C |
| ATOM | 7605 | CG | PRO | G | 433 | −9.866 | 21.948 | 55.508 | 1.00 | 29.48 | G | C |
| ATOM | 7606 | C | PRO | G | 433 | −12.129 | 23.999 | 54.226 | 1.00 | 29.13 | G | C |
| ATOM | 7607 | O | PRO | G | 433 | −12.626 | 24.093 | 53.096 | 1.00 | 31.94 | G | O |
| ATOM | 7608 | N | ASP | G | 434 | −12.867 | 23.960 | 55.333 | 1.00 | 24.08 | G | N |
| ATOM | 7609 | CA | ASP | G | 434 | −14.321 | 24.002 | 55.253 | 1.00 | 22.98 | G | C |
| ATOM | 7610 | CB | ASP | G | 434 | −14.921 | 23.222 | 56.431 | 1.00 | 29.06 | G | C |
| ATOM | 7611 | CG | ASP | G | 434 | −14.817 | 23.969 | 57.762 | 1.00 | 38.49 | G | C |
| ATOM | 7612 | OD1 | ASP | G | 434 | −14.019 | 24.929 | 57.883 | 1.00 | 43.04 | G | O |
| ATOM | 7613 | OD2 | ASP | G | 434 | −15.548 | 23.587 | 58.702 | 1.00 | 41.08 | G | O |
| ATOM | 7614 | C | ASP | G | 434 | −14.947 | 25.404 | 55.168 | 1.00 | 20.26 | G | C |
| ATOM | 7615 | O | ASP | G | 434 | −16.169 | 25.540 | 55.093 | 1.00 | 17.27 | G | O |
| ATOM | 7616 | N | GLU | G | 435 | −14.111 | 26.442 | 55.145 | 1.00 | 18.34 | G | N |
| ATOM | 7617 | CA | GLU | G | 435 | −14.604 | 27.821 | 55.095 | 1.00 | 17.70 | G | C |
| ATOM | 7618 | CB | GLU | G | 435 | −13.423 | 28.791 | 55.135 | 1.00 | 17.39 | G | C |
| ATOM | 7619 | CG | GLU | G | 435 | −12.705 | 28.807 | 56.468 | 1.00 | 18.64 | G | C |
| ATOM | 7620 | CD | GLU | G | 435 | −11.753 | 29.977 | 56.595 | 1.00 | 22.29 | G | C |
| ATOM | 7621 | OE1 | GLU | G | 435 | −10.586 | 29.752 | 56.985 | 1.00 | 17.97 | G | O |
| ATOM | 7622 | OE2 | GLU | G | 435 | −12.183 | 31.120 | 56.305 | 1.00 | 24.01 | G | O |
| ATOM | 7623 | C | GLU | G | 435 | −15.471 | 28.135 | 53.882 | 1.00 | 15.30 | G | C |
| ATOM | 7624 | O | GLU | G | 435 | −16.465 | 28.852 | 53.986 | 1.00 | 15.64 | G | O |
| ATOM | 7625 | N | TRP | G | 436 | −15.078 | 27.601 | 52.729 | 1.00 | 17.50 | G | N |
| ATOM | 7626 | CA | TRP | G | 436 | −15.806 | 27.826 | 51.483 | 1.00 | 17.32 | G | C |
| ATOM | 7627 | CB | TRP | G | 436 | −15.031 | 27.233 | 50.307 | 1.00 | 14.33 | G | C |
| ATOM | 7628 | CG | TRP | G | 436 | −13.919 | 28.104 | 49.839 | 1.00 | 11.19 | G | C |
| ATOM | 7629 | CD2 | TRP | G | 436 | −14.042 | 29.293 | 49.044 | 1.00 | 11.91 | G | C |
| ATOM | 7630 | CE2 | TRP | G | 436 | −12.738 | 29.800 | 48.836 | 1.00 | 10.48 | G | C |
| ATOM | 7631 | CE3 | TRP | G | 436 | −15.132 | 29.978 | 48.486 | 1.00 | 10.83 | G | C |
| ATOM | 7632 | CD1 | TRP | G | 436 | −12.582 | 27.939 | 50.077 | 1.00 | 13.05 | G | C |
| ATOM | 7633 | NE1 | TRP | G | 436 | −11.863 | 28.959 | 49.474 | 1.00 | 9.92 | G | N |
| ATOM | 7634 | CZ2 | TRP | G | 436 | −12.493 | 30.963 | 48.091 | 1.00 | 14.37 | G | C |
| ATOM | 7635 | CZ3 | TRP | G | 436 | −14.886 | 31.136 | 47.738 | 1.00 | 14.76 | G | C |
| ATOM | 7636 | CH2 | TRP | G | 436 | −13.572 | 31.614 | 47.550 | 1.00 | 10.43 | G | C |
| ATOM | 7637 | C | TRP | G | 436 | −17.177 | 27.182 | 51.587 | 1.00 | 19.02 | G | C |
| ATOM | 7638 | O | TRP | G | 436 | −18.198 | 27.772 | 51.192 | 1.00 | 19.42 | G | O |
| ATOM | 7639 | N | SER | G | 437 | −17.198 | 25.968 | 52.127 | 1.00 | 18.37 | G | N |
| ATOM | 7640 | CA | SER | G | 437 | −18.449 | 25.252 | 52.301 | 1.00 | 19.02 | G | C |
| ATOM | 7641 | CB | SER | G | 437 | −18.196 | 23.878 | 52.920 | 1.00 | 23.12 | G | C |
| ATOM | 7642 | OG | SER | G | 437 | −19.433 | 23.224 | 53.160 | 1.00 | 28.64 | G | O |
| ATOM | 7643 | C | SER | G | 437 | −19.407 | 26.030 | 53.189 | 1.00 | 17.21 | G | C |
| ATOM | 7644 | O | SER | G | 437 | −20.597 | 26.147 | 52.881 | 1.00 | 17.81 | G | O |
| ATOM | 7645 | N | LYS | G | 438 | −18.889 | 26.558 | 54.295 | 1.00 | 17.50 | G | N |
| ATOM | 7646 | CA | LYS | G | 438 | −19.721 | 27.325 | 55.220 | 1.00 | 17.46 | G | C |
| ATOM | 7647 | CB | LYS | G | 438 | −18.994 | 27.545 | 56.547 | 1.00 | 18.29 | G | C |
| ATOM | 7648 | CG | LYS | G | 438 | −18.748 | 26.270 | 57.311 | 1.00 | 20.31 | G | C |
| ATOM | 7649 | CD | LYS | G | 438 | −18.818 | 26.514 | 58.798 | 1.00 | 25.95 | G | C |
| ATOM | 7650 | CE | LYS | G | 438 | −17.662 | 25.814 | 59.519 | 1.00 | 34.12 | G | C |
| ATOM | 7651 | NZ | LYS | G | 438 | −17.777 | 25.891 | 61.019 | 1.00 | 37.40 | G | N |
| ATOM | 7652 | C | LYS | G | 438 | −20.136 | 28.670 | 54.643 | 1.00 | 14.82 | G | C |
| ATOM | 7653 | O | LYS | G | 438 | −21.279 | 29.084 | 54.821 | 1.00 | 16.28 | G | O |
| ATOM | 7654 | N | LEU | G | 439 | −19.227 | 29.355 | 53.953 | 1.00 | 12.68 | G | N |
| ATOM | 7655 | CA | LEU | G | 439 | −19.585 | 30.656 | 53.384 | 1.00 | 14.11 | G | C |
| ATOM | 7656 | CB | LEU | G | 439 | −18.335 | 31.381 | 52.864 | 1.00 | 12.90 | G | C |
| ATOM | 7657 | CG | LEU | G | 439 | −18.512 | 32.857 | 52.444 | 1.00 | 15.96 | G | C |
| ATOM | 7658 | CD1 | LEU | G | 439 | −19.128 | 33.699 | 53.578 | 1.00 | 12.41 | G | C |
| ATOM | 7659 | CD2 | LEU | G | 439 | −17.148 | 33.419 | 52.031 | 1.00 | 13.04 | G | C |
| ATOM | 7660 | C | LEU | G | 439 | −20.630 | 30.536 | 52.272 | 1.00 | 13.71 | G | C |
| ATOM | 7661 | O | LEU | G | 439 | −21.581 | 31.321 | 52.212 | 1.00 | 15.05 | G | O |
| ATOM | 7662 | N | SER | G | 440 | −20.475 | 29.544 | 51.394 | 1.00 | 16.58 | G | N |
| ATOM | 7663 | CA | SER | G | 440 | −21.436 | 29.378 | 50.300 | 1.00 | 15.38 | G | C |
| ATOM | 7664 | CB | SER | G | 440 | −20.982 | 28.282 | 49.330 | 1.00 | 15.95 | G | C |
| ATOM | 7665 | OG | SER | G | 440 | −20.499 | 27.142 | 50.005 | 1.00 | 20.91 | G | O |
| ATOM | 7666 | C | SER | G | 440 | −22.824 | 29.061 | 50.837 | 1.00 | 17.28 | G | C |
| ATOM | 7667 | O | SER | G | 440 | −23.816 | 29.571 | 50.322 | 1.00 | 17.37 | G | O |
| ATOM | 7668 | N | SER | G | 441 | −22.895 | 28.222 | 51.874 | 1.00 | 17.48 | G | N |
| ATOM | 7669 | CA | SER | G | 441 | −24.175 | 27.866 | 52.488 | 1.00 | 18.32 | G | C |
| ATOM | 7670 | CB | SER | G | 441 | −23.978 | 26.794 | 53.576 | 1.00 | 18.62 | G | C |
| ATOM | 7671 | OG | SER | G | 441 | −23.580 | 25.549 | 53.019 | 1.00 | 23.96 | G | O |
| ATOM | 7672 | C | SER | G | 441 | −24.815 | 29.105 | 53.110 | 1.00 | 16.74 | G | C |
| ATOM | 7673 | O | SER | G | 441 | −26.030 | 29.322 | 53.001 | 1.00 | 19.02 | G | O |
| ATOM | 7674 | N | TRP | G | 442 | −23.991 | 29.916 | 53.767 | 1.00 | 16.51 | G | N |
| ATOM | 7675 | CA | TRP | G | 442 | −24.458 | 31.143 | 54.408 | 1.00 | 15.76 | G | C |
| ATOM | 7676 | CB | TRP | G | 442 | −23.267 | 31.843 | 55.105 | 1.00 | 15.55 | G | C |
| ATOM | 7677 | CG | TRP | G | 442 | −23.561 | 33.240 | 55.609 | 1.00 | 19.22 | G | C |
| ATOM | 7678 | CD2 | TRP | G | 442 | −23.281 | 34.491 | 54.938 | 1.00 | 21.36 | G | C |
| ATOM | 7679 | CE2 | TRP | G | 442 | −23.793 | 35.529 | 55.761 | 1.00 | 19.99 | G | C |
| ATOM | 7680 | CE3 | TRP | G | 442 | −22.655 | 34.834 | 53.725 | 1.00 | 20.16 | G | C |
| ATOM | 7681 | CD1 | TRP | G | 442 | −24.202 | 33.569 | 56.771 | 1.00 | 18.55 | G | C |
| ATOM | 7682 | NE1 | TRP | G | 442 | −24.344 | 34.936 | 56.868 | 1.00 | 21.09 | G | N |
| ATOM | 7683 | CZ2 | TRP | G | 442 | −23.699 | 36.892 | 55.414 | 1.00 | 17.50 | G | C |
| ATOM | 7684 | CZ3 | TRP | G | 442 | −22.561 | 36.198 | 53.374 | 1.00 | 21.74 | G | C |
| ATOM | 7685 | CH2 | TRP | G | 442 | −23.085 | 37.208 | 54.223 | 1.00 | 19.89 | G | C |
| ATOM | 7686 | C | TRP | G | 442 | −25.077 | 32.065 | 53.352 | 1.00 | 15.60 | G | C |
| ATOM | 7687 | O | TRP | G | 442 | −26.166 | 32.615 | 53.524 | 1.00 | 13.60 | G | O |
| ATOM | 7688 | N | PHE | G | 443 | −24.361 | 32.221 | 52.245 | 1.00 | 18.89 | G | N |
| ATOM | 7689 | CA | PHE | G | 443 | −24.793 | 33.090 | 51.159 | 1.00 | 16.29 | G | C |
| ATOM | 7690 | CB | PHE | G | 443 | −23.639 | 33.226 | 50.149 | 1.00 | 20.00 | G | C |
| ATOM | 7691 | CG | PHE | G | 443 | −23.873 | 34.270 | 49.084 | 1.00 | 20.35 | G | C |
| ATOM | 7692 | CD1 | PHE | G | 443 | −24.588 | 33.956 | 47.923 | 1.00 | 22.11 | G | C |
| ATOM | 7693 | CD2 | PHE | G | 443 | −23.379 | 35.558 | 49.237 | 1.00 | 17.95 | G | C |
| ATOM | 7694 | CE1 | PHE | G | 443 | −24.805 | 34.914 | 46.927 | 1.00 | 20.92 | G | C |
| ATOM | 7695 | CE2 | PHE | G | 443 | −23.590 | 36.521 | 48.252 | 1.00 | 20.83 | G | C |
| ATOM | 7696 | CZ | PHE | G | 443 | −24.305 | 36.198 | 47.095 | 1.00 | 20.36 | G | C |
| ATOM | 7697 | C | PHE | G | 443 | −26.057 | 32.598 | 50.464 | 1.00 | 16.97 | G | C |
| ATOM | 7698 | O | PHE | G | 443 | −27.019 | 33.360 | 50.279 | 1.00 | 17.73 | G | O |
| ATOM | 7699 | N | VAL | G | 444 | −26.064 | 31.326 | 50.078 | 1.00 | 17.19 | G | N |
| ATOM | 7700 | CA | VAL | G | 444 | −27.208 | 30.754 | 49.372 | 1.00 | 16.82 | G | C |
| ATOM | 7701 | CB | VAL | G | 444 | −26.850 | 29.383 | 48.787 | 1.00 | 19.54 | G | C |
| ATOM | 7702 | CG1 | VAL | G | 444 | −28.053 | 28.791 | 48.089 | 1.00 | 18.37 | G | C |
| ATOM | 7703 | CG2 | VAL | G | 444 | −25.685 | 29.524 | 47.801 | 1.00 | 17.89 | G | C |
| ATOM | 7704 | C | VAL | G | 444 | −28.430 | 30.609 | 50.260 | 1.00 | 20.05 | G | C |
| ATOM | 7705 | O | VAL | G | 444 | −29.529 | 31.034 | 49.893 | 1.00 | 17.06 | G | O |
| ATOM | 7706 | N | ARG | G | 445 | −28.245 | 30.021 | 51.441 | 1.00 | 22.43 | G | N |
| ATOM | 7707 | CA | ARG | G | 445 | −29.363 | 29.829 | 52.362 | 1.00 | 22.18 | G | C |
| ATOM | 7708 | CB | ARG | G | 445 | −28.907 | 29.040 | 53.574 | 1.00 | 24.12 | G | C |
| ATOM | 7709 | CG | ARG | G | 445 | −28.972 | 27.552 | 53.358 | 1.00 | 29.40 | G | C |
| ATOM | 7710 | CD | ARG | G | 445 | −27.848 | 26.851 | 54.070 | 1.00 | 34.25 | G | C |
| ATOM | 7711 | NE | ARG | G | 445 | −27.467 | 25.628 | 53.382 | 1.00 | 37.96 | G | N |
| ATOM | 7712 | CZ | ARG | G | 445 | −27.199 | 24.486 | 53.995 | 1.00 | 40.14 | G | C |
| ATOM | 7713 | NH1 | ARG | G | 445 | −27.267 | 24.399 | 55.316 | 1.00 | 42.93 | G | N |
| ATOM | 7714 | NH2 | ARG | G | 445 | −26.872 | 23.428 | 53.288 | 1.00 | 40.75 | G | N |
| ATOM | 7715 | C | ARG | G | 445 | −30.031 | 31.120 | 52.811 | 1.00 | 23.26 | G | C |
| ATOM | 7716 | O | ARG | G | 445 | −31.250 | 31.170 | 52.974 | 1.00 | 24.25 | G | O |
| ATOM | 7717 | N | ASN | G | 446 | −29.249 | 32.172 | 53.020 | 1.00 | 22.11 | G | N |
| ATOM | 7718 | CA | ASN | G | 446 | −29.834 | 33.438 | 53.436 | 1.00 | 20.70 | G | C |
| ATOM | 7719 | CB | ASN | G | 446 | −28.822 | 34.240 | 54.259 | 1.00 | 22.03 | G | C |
| ATOM | 7720 | CG | ASN | G | 446 | −28.609 | 33.658 | 55.654 | 1.00 | 21.44 | G | C |
| ATOM | 7721 | OD1 | ASN | G | 446 | −27.596 | 33.003 | 55.927 | 1.00 | 20.27 | G | O |
| ATOM | 7722 | ND2 | ASN | G | 446 | −29.561 | 33.903 | 56.545 | 1.00 | 19.54 | G | N |
| ATOM | 7723 | C | ASN | G | 446 | −30.287 | 34.244 | 52.211 | 1.00 | 20.35 | G | C |
| ATOM | 7724 | O | ASN | G | 446 | −30.819 | 35.352 | 52.341 | 1.00 | 18.70 | G | O |
| ATOM | 7725 | N | ARG | G | 447 | −30.088 | 33.666 | 51.028 | 1.00 | 21.31 | G | N |
| ATOM | 7726 | CA | ARG | G | 447 | −30.463 | 34.307 | 49.773 | 1.00 | 24.29 | G | C |
| ATOM | 7727 | CB | ARG | G | 447 | −31.998 | 34.339 | 49.592 | 1.00 | 25.03 | G | C |
| ATOM | 7728 | CG | ARG | G | 447 | −32.726 | 33.069 | 50.057 | 1.00 | 31.47 | G | C |
| ATOM | 7729 | CD | ARG | G | 447 | −33.081 | 32.116 | 48.927 | 1.00 | 35.30 | G | C |
| ATOM | 7730 | NE | ARG | G | 447 | −33.878 | 32.763 | 47.884 | 1.00 | 41.12 | G | N |
| ATOM | 7731 | CZ | ARG | G | 447 | −33.990 | 32.301 | 46.639 | 1.00 | 43.29 | G | C |
| ATOM | 7732 | NH1 | ARG | G | 447 | −33.362 | 31.184 | 46.276 | 1.00 | 43.78 | G | N |
| ATOM | 7733 | NH2 | ARG | G | 447 | −34.718 | 32.964 | 45.746 | 1.00 | 45.08 | G | N |
| ATOM | 7734 | C | ARG | G | 447 | −29.905 | 35.723 | 49.731 | 1.00 | 22.85 | G | C |
| ATOM | 7735 | O | ARG | G | 447 | −30.642 | 36.697 | 49.631 | 1.00 | 21.32 | G | O |
| ATOM | 7736 | N | ILE | G | 448 | −28.592 | 35.829 | 49.846 | 1.00 | 24.39 | G | N |
| ATOM | 7737 | CA | ILE | G | 448 | −27.960 | 37.127 | 49.787 | 1.00 | 26.04 | G | C |
| ATOM | 7738 | CB | ILE | G | 448 | −26.607 | 37.113 | 50.526 | 1.00 | 24.22 | G | C |
| ATOM | 7739 | CG2 | ILE | G | 448 | −25.816 | 38.372 | 50.234 | 1.00 | 24.96 | G | C |
| ATOM | 7740 | CG1 | ILE | G | 448 | −26.853 | 37.024 | 52.026 | 1.00 | 24.10 | G | C |
| ATOM | 7741 | CD1 | ILE | G | 448 | −25.949 | 36.061 | 52.689 | 1.00 | 28.25 | G | C |
| ATOM | 7742 | C | ILE | G | 448 | −27.771 | 37.374 | 48.290 | 1.00 | 27.78 | G | C |
| ATOM | 7743 | O | ILE | G | 448 | −27.063 | 36.654 | 47.588 | 1.00 | 32.29 | G | O |
| ATOM | 7744 | N | TYR | G | 449 | −28.461 | 38.364 | 47.780 | 1.00 | 28.16 | G | N |
| ATOM | 7745 | CA | TYR | G | 449 | −28.338 | 38.675 | 46.380 | 1.00 | 26.19 | G | C |
| ATOM | 7746 | CB | TYR | G | 449 | −28.883 | 37.556 | 45.483 | 1.00 | 27.21 | G | C |
| ATOM | 7747 | CG | TYR | G | 449 | −29.213 | 38.102 | 44.116 | 1.00 | 27.29 | G | C |
| ATOM | 7748 | CD1 | TYR | G | 449 | −28.228 | 38.211 | 43.132 | 1.00 | 26.65 | G | C |
| ATOM | 7749 | CE1 | TYR | G | 449 | −28.479 | 38.876 | 41.942 | 1.00 | 26.97 | G | C |
| ATOM | 7750 | CD2 | TYR | G | 449 | −30.461 | 38.662 | 43.862 | 1.00 | 27.12 | G | C |
| ATOM | 7751 | CE2 | TYR | G | 449 | −30.722 | 39.329 | 42.677 | 1.00 | 29.50 | G | C |
| ATOM | 7752 | CZ | TYR | G | 449 | −29.729 | 39.438 | 41.725 | 1.00 | 29.30 | G | C |
| ATOM | 7753 | OH | TYR | G | 449 | −29.998 | 40.132 | 40.571 | 1.00 | 34.24 | G | O |
| ATOM | 7754 | C | TYR | G | 449 | −29.182 | 39.903 | 46.226 | 1.00 | 24.01 | G | C |
| ATOM | 7755 | O | TYR | G | 449 | −30.367 | 39.890 | 46.526 | 1.00 | 27.42 | G | O |
| ATOM | 7756 | N | SER | G | 450 | −28.554 | 40.971 | 45.780 | 1.00 | 21.42 | G | N |
| ATOM | 7757 | CA | SER | G | 450 | −29.233 | 42.233 | 45.580 | 1.00 | 20.17 | G | C |
| ATOM | 7758 | CB | SER | G | 450 | −28.715 | 43.264 | 46.606 | 1.00 | 18.67 | G | C |
| ATOM | 7759 | OG | SER | G | 450 | −28.834 | 44.616 | 46.162 | 1.00 | 25.05 | G | O |
| ATOM | 7760 | C | SER | G | 450 | −28.817 | 42.591 | 44.162 | 1.00 | 19.45 | G | C |
| ATOM | 7761 | O | SER | G | 450 | −27.721 | 42.229 | 43.724 | 1.00 | 20.06 | G | O |
| ATOM | 7762 | N | SER | G | 451 | −29.689 | 43.265 | 43.430 | 1.00 | 17.61 | G | N |
| ATOM | 7763 | CA | SER | G | 451 | −29.346 | 43.623 | 42.077 | 1.00 | 19.46 | G | C |
| ATOM | 7764 | CB | SER | G | 451 | −30.604 | 43.998 | 41.308 | 1.00 | 18.86 | G | C |
| ATOM | 7765 | OG | SER | G | 451 | −31.239 | 45.064 | 41.965 | 1.00 | 27.67 | G | O |
| ATOM | 7766 | C | SER | G | 451 | −28.351 | 44.784 | 42.091 | 1.00 | 19.14 | G | C |
| ATOM | 7767 | O | SER | G | 451 | −27.821 | 45.160 | 41.047 | 1.00 | 21.67 | G | O |
| ATOM | 7768 | N | ASN | G | 452 | −28.078 | 45.341 | 43.273 | 1.00 | 17.71 | G | N |
| ATOM | 7769 | CA | ASN | G | 452 | −27.139 | 46.459 | 43.363 | 1.00 | 14.79 | G | C |
| ATOM | 7770 | CB | ASN | G | 452 | −27.809 | 47.671 | 43.992 | 1.00 | 13.17 | G | C |
| ATOM | 7771 | CG | ASN | G | 452 | −28.772 | 48.367 | 43.043 | 1.00 | 15.01 | G | C |
| ATOM | 7772 | OD1 | ASN | G | 452 | −29.743 | 47.767 | 42.560 | 1.00 | 13.53 | G | O |
| ATOM | 7773 | ND2 | ASN | G | 452 | −28.510 | 49.652 | 42.778 | 1.00 | 12.83 | G | N |
| ATOM | 7774 | C | ASN | G | 452 | −25.856 | 46.135 | 44.121 | 1.00 | 14.98 | G | C |
| ATOM | 7775 | O | ASN | G | 452 | −25.144 | 47.043 | 44.575 | 1.00 | 13.00 | G | O |
| ATOM | 7776 | N | MET | G | 453 | −25.551 | 44.841 | 44.230 | 1.00 | 13.20 | G | N |
| ATOM | 7777 | CA | MET | G | 453 | −24.344 | 44.390 | 44.905 | 1.00 | 12.10 | G | C |
| ATOM | 7778 | CB | MET | G | 453 | −24.652 | 43.902 | 46.325 | 1.00 | 11.29 | G | C |
| ATOM | 7779 | CG | MET | G | 453 | −24.943 | 44.981 | 47.345 | 1.00 | 17.63 | G | C |
| ATOM | 7780 | SD | MET | G | 453 | −25.154 | 44.291 | 49.023 | 1.00 | 22.06 | G | S |
| ATOM | 7781 | CE | MET | G | 453 | −24.616 | 45.665 | 49.975 | 1.00 | 23.57 | G | C |
| ATOM | 7782 | C | MET | G | 453 | −23.750 | 43.218 | 44.166 | 1.00 | 13.20 | G | C |
| ATOM | 7783 | O | MET | G | 453 | −24.486 | 42.326 | 43.747 | 1.00 | 13.93 | G | O |
| ATOM | 7784 | N | THR | G | 454 | −22.428 | 43.231 | 43.996 | 1.00 | 11.84 | G | N |
| ATOM | 7785 | CA | THR | G | 454 | −21.709 | 42.115 | 43.397 | 1.00 | 12.18 | G | C |
| ATOM | 7786 | CB | THR | G | 454 | −21.041 | 42.455 | 42.023 | 1.00 | 12.72 | G | C |
| ATOM | 7787 | OG1 | THR | G | 454 | −20.290 | 43.672 | 42.099 | 1.00 | 14.77 | G | O |
| ATOM | 7788 | CG2 | THR | G | 454 | −22.127 | 42.575 | 40.959 | 1.00 | 7.66 | G | C |
| ATOM | 7789 | C | THR | G | 454 | −20.694 | 41.771 | 44.486 | 1.00 | 12.97 | G | C |
| ATOM | 7790 | O | THR | G | 454 | −20.397 | 42.613 | 45.334 | 1.00 | 14.53 | G | O |
| ATOM | 7791 | N | TRP | G | 455 | −20.169 | 40.548 | 44.475 | 1.00 | 13.65 | G | N |
| ATOM | 7792 | CA | TRP | G | 455 | −19.294 | 40.095 | 45.543 | 1.00 | 13.83 | G | C |
| ATOM | 7793 | CB | TRP | G | 455 | −19.988 | 38.927 | 46.271 | 1.00 | 12.74 | G | C |
| ATOM | 7794 | CG | TRP | G | 455 | −21.334 | 39.327 | 46.814 | 1.00 | 13.31 | G | C |
| ATOM | 7795 | CD2 | TRP | G | 455 | −21.597 | 39.875 | 48.112 | 1.00 | 15.25 | G | C |
| ATOM | 7796 | CE2 | TRP | G | 455 | −22.971 | 40.234 | 48.150 | 1.00 | 14.70 | G | C |
| ATOM | 7797 | CE3 | TRP | G | 455 | −20.805 | 40.103 | 49.247 | 1.00 | 11.76 | G | C |
| ATOM | 7798 | CD1 | TRP | G | 455 | −22.531 | 39.362 | 46.134 | 1.00 | 14.99 | G | C |
| ATOM | 7799 | NE1 | TRP | G | 455 | −23.520 | 39.911 | 46.933 | 1.00 | 14.91 | G | N |
| ATOM | 7800 | CZ2 | TRP | G | 455 | −23.559 | 40.806 | 49.280 | 1.00 | 12.94 | G | C |
| ATOM | 7801 | CZ3 | TRP | G | 455 | −21.399 | 40.675 | 50.368 | 1.00 | 13.75 | G | C |
| ATOM | 7802 | CH2 | TRP | G | 455 | −22.759 | 41.018 | 50.373 | 1.00 | 12.68 | G | C |
| ATOM | 7803 | C | TRP | G | 455 | −17.871 | 39.704 | 45.208 | 1.00 | 16.85 | G | C |
| ATOM | 7804 | O | TRP | G | 455 | −17.575 | 39.244 | 44.113 | 1.00 | 14.60 | G | O |
| ATOM | 7805 | N | MET | G | 456 | −16.995 | 39.891 | 46.193 | 1.00 | 16.75 | G | N |
| ATOM | 7806 | CA | MET | G | 456 | −15.588 | 39.549 | 46.072 | 1.00 | 15.34 | G | C |
| ATOM | 7807 | CB | MET | G | 456 | −14.744 | 40.806 | 45.917 | 1.00 | 14.00 | G | C |
| ATOM | 7808 | CG | MET | G | 456 | −15.026 | 41.556 | 44.627 | 1.00 | 14.55 | G | C |
| ATOM | 7809 | SD | MET | G | 456 | −13.947 | 42.997 | 44.405 | 1.00 | 19.96 | G | S |
| ATOM | 7810 | CE | MET | G | 456 | −12.293 | 42.272 | 44.704 | 1.00 | 10.98 | G | C |
| ATOM | 7811 | C | MET | G | 456 | −15.197 | 38.835 | 47.344 | 1.00 | 15.26 | G | C |
| ATOM | 7812 | O | MET | G | 456 | −15.946 | 38.852 | 48.332 | 1.00 | 15.04 | G | O |
| ATOM | 7813 | N | ILE | G | 457 | −14.038 | 38.190 | 47.319 | 1.00 | 15.82 | G | N |
| ATOM | 7814 | CA | ILE | G | 457 | −13.542 | 37.492 | 48.499 | 1.00 | 16.60 | G | C |
| ATOM | 7815 | CB | ILE | G | 457 | −13.389 | 35.950 | 48.254 | 1.00 | 18.04 | G | C |
| ATOM | 7816 | CG2 | ILE | G | 457 | −12.383 | 35.338 | 49.230 | 1.00 | 13.00 | G | C |
| ATOM | 7817 | CG1 | ILE | G | 457 | −14.729 | 35.258 | 48.509 | 1.00 | 18.59 | G | C |
| ATOM | 7818 | CD1 | ILE | G | 457 | −15.300 | 34.686 | 47.302 | 1.00 | 26.79 | G | C |
| ATOM | 7819 | C | ILE | G | 457 | −12.198 | 38.098 | 48.860 | 1.00 | 17.14 | G | C |
| ATOM | 7820 | O | ILE | G | 457 | −11.357 | 38.308 | 47.994 | 1.00 | 15.87 | G | O |
| ATOM | 7821 | N | GLN | G | 458 | −12.018 | 38.434 | 50.134 | 1.00 | 16.45 | G | N |
| ATOM | 7822 | CA | GLN | G | 458 | −10.741 | 38.978 | 50.573 | 1.00 | 15.96 | G | C |
| ATOM | 7823 | CB | GLN | G | 458 | −10.937 | 40.275 | 51.360 | 1.00 | 16.33 | G | C |
| ATOM | 7824 | CG | GLN | G | 458 | −11.669 | 40.088 | 52.665 | 1.00 | 18.11 | G | C |
| ATOM | 7825 | CD | GLN | G | 458 | −11.911 | 41.395 | 53.394 | 1.00 | 18.49 | G | C |
| ATOM | 7826 | OE1 | GLN | G | 458 | −11.894 | 42.465 | 52.807 | 1.00 | 13.83 | G | O |
| ATOM | 7827 | NE2 | GLN | G | 458 | −12.143 | 41.302 | 54.691 | 1.00 | 20.22 | G | N |
| ATOM | 7828 | C | GLN | G | 458 | −10.077 | 37.947 | 51.468 | 1.00 | 14.80 | G | C |
| ATOM | 7829 | O | GLN | G | 458 | −10.731 | 37.325 | 52.305 | 1.00 | 14.51 | G | O |
| ATOM | 7830 | N | VAL | G | 459 | −8.792 | 37.719 | 51.262 | 1.00 | 14.48 | G | N |
| ATOM | 7831 | CA | VAL | G | 459 | −8.119 | 36.799 | 52.136 | 1.00 | 16.32 | G | C |
| ATOM | 7832 | CB | VAL | G | 459 | −7.584 | 35.502 | 51.396 | 1.00 | 18.67 | G | C |
| ATOM | 7833 | CG1 | VAL | G | 459 | −8.273 | 35.321 | 50.058 | 1.00 | 15.56 | G | C |
| ATOM | 7834 | CG2 | VAL | G | 459 | −6.085 | 35.519 | 51.286 | 1.00 | 21.37 | G | C |
| ATOM | 7835 | C | VAL | G | 459 | −7.030 | 37.603 | 52.839 | 1.00 | 14.63 | G | C |
| ATOM | 7836 | O | VAL | G | 459 | −6.133 | 38.155 | 52.221 | 1.00 | 15.26 | G | O |
| ATOM | 7837 | N | PRO | G | 460 | −7.166 | 37.750 | 54.162 | 1.00 | 18.36 | G | N |
| ATOM | 7838 | CD | PRO | G | 460 | −8.306 | 37.238 | 54.948 | 1.00 | 18.29 | G | C |
| ATOM | 7839 | CA | PRO | G | 460 | −6.220 | 38.486 | 55.003 | 1.00 | 15.36 | G | C |
| ATOM | 7840 | CB | PRO | G | 460 | −6.883 | 38.467 | 56.376 | 1.00 | 14.01 | G | C |
| ATOM | 7841 | CG | PRO | G | 460 | −8.337 | 38.170 | 56.099 | 1.00 | 19.03 | G | C |
| ATOM | 7842 | C | PRO | G | 460 | −4.840 | 37.839 | 55.019 | 1.00 | 16.04 | G | C |
| ATOM | 7843 | O | PRO | G | 460 | −4.724 | 36.607 | 55.037 | 1.00 | 16.54 | G | O |
| ATOM | 7844 | N | ARG | G | 461 | −3.792 | 38.656 | 54.999 | 1.00 | 14.53 | G | N |
| ATOM | 7845 | CA | ARG | G | 461 | −2.434 | 38.123 | 55.010 | 1.00 | 16.97 | G | C |
| ATOM | 7846 | CB | ARG | G | 461 | −1.479 | 39.081 | 54.285 | 1.00 | 14.15 | G | C |
| ATOM | 7847 | CG | ARG | G | 461 | −1.909 | 39.469 | 52.873 | 1.00 | 15.12 | G | C |
| ATOM | 7848 | CD | ARG | G | 461 | −0.806 | 40.210 | 52.116 | 1.00 | 13.91 | G | C |
| ATOM | 7849 | NE | ARG | G | 461 | −0.582 | 41.558 | 52.649 | 1.00 | 15.51 | G | N |
| ATOM | 7850 | CZ | ARG | G | 461 | −1.334 | 42.617 | 52.370 | 1.00 | 13.75 | G | C |
| ATOM | 7851 | NH1 | ARG | G | 461 | −2.385 | 42.519 | 51.556 | 1.00 | 17.03 | G | N |
| ATOM | 7852 | NH2 | ARG | G | 461 | −1.027 | 43.786 | 52.896 | 1.00 | 17.98 | G | N |
| ATOM | 7853 | C | ARG | G | 461 | −1.999 | 37.930 | 56.473 | 1.00 | 20.36 | G | C |
| ATOM | 7854 | O | ARG | G | 461 | −1.141 | 38.659 | 57.006 | 1.00 | 21.24 | G | O |
| ATOM | 7855 | N | ILE | G | 462 | −2.596 | 36.937 | 57.121 | 1.00 | 20.25 | G | N |
| ATOM | 7856 | CA | ILE | G | 462 | −2.298 | 36.689 | 58.513 | 1.00 | 20.24 | G | C |
| ATOM | 7857 | CB | ILE | G | 462 | −3.503 | 37.076 | 59.423 | 1.00 | 18.31 | G | C |
| ATOM | 7858 | CG2 | ILE | G | 462 | −3.894 | 38.540 | 59.180 | 1.00 | 17.88 | G | C |
| ATOM | 7859 | CG1 | ILE | G | 462 | −4.688 | 36.146 | 59.161 | 1.00 | 15.76 | G | C |
| ATOM | 7860 | CD1 | ILE | G | 462 | −5.957 | 36.547 | 59.905 | 1.00 | 12.72 | G | C |
| ATOM | 7861 | C | ILE | G | 462 | −1.901 | 35.252 | 58.794 | 1.00 | 22.37 | G | C |
| ATOM | 7862 | O | ILE | G | 462 | −2.342 | 34.661 | 59.783 | 1.00 | 24.54 | G | O |
| ATOM | 7863 | N | TYR | G | 463 | −1.070 | 34.689 | 57.927 | 1.00 | 22.14 | G | N |
| ATOM | 7864 | CA | TYR | G | 463 | −0.590 | 33.329 | 58.128 | 1.00 | 21.65 | G | C |
| ATOM | 7865 | CB | TYR | G | 463 | 0.365 | 32.930 | 57.006 | 1.00 | 19.09 | G | C |
| ATOM | 7866 | CG | TYR | G | 463 | 1.392 | 31.893 | 57.423 | 1.00 | 19.58 | G | C |
| ATOM | 7867 | CD1 | TYR | G | 463 | 1.096 | 30.532 | 57.360 | 1.00 | 16.43 | G | C |
| ATOM | 7868 | CE1 | TYR | G | 463 | 2.022 | 29.568 | 57.775 | 1.00 | 18.09 | G | C |
| ATOM | 7869 | CD2 | TYR | G | 463 | 2.647 | 32.279 | 57.909 | 1.00 | 17.81 | G | C |
| ATOM | 7870 | CE2 | TYR | G | 463 | 3.583 | 31.330 | 58.325 | 1.00 | 17.44 | G | C |
| ATOM | 7871 | CZ | TYR | G | 463 | 3.265 | 29.973 | 58.257 | 1.00 | 22.61 | G | C |
| ATOM | 7872 | OH | TYR | G | 463 | 4.199 | 29.020 | 58.657 | 1.00 | 23.53 | G | O |
| ATOM | 7873 | C | TYR | G | 463 | 0.154 | 33.239 | 59.473 | 1.00 | 22.89 | G | C |
| ATOM | 7874 | O | TYR | G | 463 | 0.034 | 32.244 | 60.199 | 1.00 | 20.38 | G | O |
| ATOM | 7875 | N | ASP | G | 464 | 0.917 | 34.280 | 59.803 | 1.00 | 23.08 | G | N |
| ATOM | 7876 | CA | ASP | G | 464 | 1.677 | 34.280 | 61.051 | 1.00 | 24.30 | G | C |
| ATOM | 7877 | CB | ASP | G | 464 | 2.530 | 35.554 | 61.178 | 1.00 | 23.11 | G | C |
| ATOM | 7878 | CG | ASP | G | 464 | 1.737 | 36.832 | 60.944 | 1.00 | 26.23 | G | C |
| ATOM | 7879 | OD1 | ASP | G | 464 | 2.249 | 37.903 | 61.322 | 1.00 | 30.12 | G | O |
| ATOM | 7880 | OD2 | ASP | G | 464 | 0.621 | 36.783 | 60.389 | 1.00 | 27.18 | G | O |
| ATOM | 7881 | C | ASP | G | 464 | 0.771 | 34.121 | 62.263 | 1.00 | 25.79 | G | C |
| ATOM | 7882 | O | ASP | G | 464 | 1.131 | 33.432 | 63.217 | 1.00 | 27.23 | G | O |
| ATOM | 7883 | N | VAL | G | 465 | −0.403 | 34.747 | 62.224 | 1.00 | 24.78 | G | N |
| ATOM | 7884 | CA | VAL | G | 465 | −1.351 | 34.641 | 63.320 | 1.00 | 23.82 | G | C |
| ATOM | 7885 | CB | VAL | G | 465 | −2.568 | 35.541 | 63.059 | 1.00 | 22.43 | G | C |
| ATOM | 7886 | CG1 | VAL | G | 465 | −3.626 | 35.301 | 64.093 | 1.00 | 23.05 | G | C |
| ATOM | 7887 | CG2 | VAL | G | 465 | −2.146 | 36.986 | 63.084 | 1.00 | 20.00 | G | C |
| ATOM | 7888 | C | VAL | G | 465 | −1.805 | 33.180 | 63.479 | 1.00 | 27.22 | G | C |
| ATOM | 7889 | O | VAL | G | 465 | −1.781 | 32.622 | 64.582 | 1.00 | 23.94 | G | O |
| ATOM | 7890 | N | PHE | G | 466 | −2.207 | 32.560 | 62.368 | 1.00 | 28.17 | G | N |
| ATOM | 7891 | CA | PHE | G | 466 | −2.674 | 31.171 | 62.372 | 1.00 | 28.04 | G | C |
| ATOM | 7892 | CB | PHE | G | 466 | −3.277 | 30.804 | 61.011 | 1.00 | 25.70 | G | C |
| ATOM | 7893 | CG | PHE | G | 466 | −4.510 | 31.575 | 60.671 | 1.00 | 26.73 | G | C |
| ATOM | 7894 | CD1 | PHE | G | 466 | −5.395 | 31.973 | 61.669 | 1.00 | 27.78 | G | C |
| ATOM | 7895 | CD2 | PHE | G | 466 | −4.799 | 31.897 | 59.354 | 1.00 | 26.67 | G | C |
| ATOM | 7896 | CE1 | PHE | G | 466 | −6.552 | 32.679 | 61.361 | 1.00 | 28.95 | G | C |
| ATOM | 7897 | CE2 | PHE | G | 466 | −5.953 | 32.604 | 59.033 | 1.00 | 28.30 | G | C |
| ATOM | 7898 | CZ | PHE | G | 466 | −6.832 | 32.995 | 60.039 | 1.00 | 29.07 | G | C |
| ATOM | 7899 | C | PHE | G | 466 | −1.542 | 30.206 | 62.680 | 1.00 | 29.29 | G | C |
| ATOM | 7900 | O | PHE | G | 466 | −1.751 | 29.178 | 63.314 | 1.00 | 29.32 | G | O |
| ATOM | 7901 | N | ARG | G | 467 | −0.343 | 30.535 | 62.212 | 1.00 | 29.60 | G | N |
| ATOM | 7902 | CA | ARG | G | 467 | 0.816 | 29.683 | 62.437 | 1.00 | 30.35 | G | C |
| ATOM | 7903 | CB | ARG | G | 467 | 2.013 | 30.175 | 61.627 | 1.00 | 30.89 | G | C |
| ATOM | 7904 | CG | ARG | G | 467 | 3.283 | 29.363 | 61.851 | 1.00 | 30.89 | G | C |
| ATOM | 7905 | CD | ARG | G | 467 | 3.016 | 27.869 | 61.684 | 1.00 | 34.03 | G | C |
| ATOM | 7906 | NE | ARG | G | 467 | 4.218 | 27.054 | 61.852 | 1.00 | 38.15 | G | N |
| ATOM | 7907 | CZ | ARG | G | 467 | 4.880 | 26.926 | 62.999 | 1.00 | 44.72 | G | C |
| ATOM | 7908 | NH1 | ARG | G | 467 | 4.465 | 27.559 | 64.098 | 1.00 | 48.79 | G | N |
| ATOM | 7909 | NH2 | ARG | G | 467 | 5.972 | 26.177 | 63.053 | 1.00 | 45.51 | G | N |
| ATOM | 7910 | C | ARG | G | 467 | 1.210 | 29.633 | 63.902 | 1.00 | 32.50 | G | C |
| ATOM | 7911 | O | ARG | G | 467 | 1.483 | 28.565 | 64.439 | 1.00 | 33.58 | G | O |
| ATOM | 7912 | N | SER | G | 468 | 1.249 | 30.794 | 64.546 | 1.00 | 33.43 | G | N |
| ATOM | 7913 | CA | SER | G | 468 | 1.624 | 30.859 | 65.946 | 1.00 | 33.54 | G | C |
| ATOM | 7914 | CB | SER | G | 468 | 1.836 | 32.319 | 66.350 | 1.00 | 33.55 | G | C |
| ATOM | 7915 | OG | SER | G | 468 | 0.638 | 33.064 | 66.206 | 1.00 | 41.04 | G | O |
| ATOM | 7916 | C | SER | G | 468 | 0.584 | 30.185 | 66.848 | 1.00 | 33.07 | G | C |
| ATOM | 7917 | O | SER | G | 468 | 0.909 | 29.762 | 67.958 | 1.00 | 33.78 | G | O |
| ATOM | 7918 | N | LYS | G | 469 | −0.654 | 30.084 | 66.361 | 1.00 | 32.92 | G | N |
| ATOM | 7919 | CA | LYS | G | 469 | −1.755 | 29.455 | 67.097 | 1.00 | 31.13 | G | C |
| ATOM | 7920 | CB | LYS | G | 469 | −3.092 | 30.100 | 66.717 | 1.00 | 31.41 | G | C |
| ATOM | 7921 | CG | LYS | G | 469 | −3.560 | 31.247 | 67.606 | 1.00 | 33.65 | G | C |
| ATOM | 7922 | CD | LYS | G | 469 | −4.950 | 31.707 | 67.159 | 1.00 | 38.52 | G | C |
| ATOM | 7923 | CE | LYS | G | 469 | −5.307 | 33.090 | 67.692 | 1.00 | 40.70 | G | C |
| ATOM | 7924 | NZ | LYS | G | 469 | −4.195 | 34.075 | 67.553 | 1.00 | 40.70 | G | N |
| ATOM | 7925 | C | LYS | G | 469 | −1.793 | 27.986 | 66.686 | 1.00 | 32.79 | G | C |
| ATOM | 7926 | O | LYS | G | 469 | −2.673 | 27.227 | 67.099 | 1.00 | 34.00 | G | O |
| ATOM | 7927 | N | ASN | G | 470 | −0.839 | 27.599 | 65.847 | 1.00 | 32.16 | G | N |
| ATOM | 7928 | CA | ASN | G | 470 | −0.752 | 26.238 | 65.337 | 1.00 | 32.57 | G | C |
| ATOM | 7929 | CB | ASN | G | 470 | −0.424 | 25.278 | 66.468 | 1.00 | 37.38 | G | C |
| ATOM | 7930 | CG | ASN | G | 470 | 0.859 | 25.651 | 67.175 | 1.00 | 42.59 | G | C |
| ATOM | 7931 | OD1 | ASN | G | 470 | 1.936 | 25.660 | 66.568 | 1.00 | 45.44 | G | O |
| ATOM | 7932 | ND2 | ASN | G | 470 | 0.758 | 25.976 | 68.469 | 1.00 | 47.64 | G | N |
| ATOM | 7933 | C | ASN | G | 470 | −2.025 | 25.797 | 64.635 | 1.00 | 32.86 | G | C |
| ATOM | 7934 | O | ASN | G | 470 | −2.460 | 24.651 | 64.761 | 1.00 | 33.72 | G | O |
| ATOM | 7935 | N | PHE | G | 471 | −2.629 | 26.718 | 63.901 | 1.00 | 33.27 | G | N |
| ATOM | 7936 | CA | PHE | G | 471 | −3.831 | 26.403 | 63.157 | 1.00 | 32.80 | G | C |
| ATOM | 7937 | CB | PHE | G | 471 | −4.653 | 27.669 | 62.905 | 1.00 | 33.07 | G | C |
| ATOM | 7938 | CG | PHE | G | 471 | −5.584 | 28.013 | 64.027 | 1.00 | 36.10 | G | C |
| ATOM | 7939 | CD1 | PHE | G | 471 | −5.745 | 27.143 | 65.102 | 1.00 | 38.43 | G | C |
| ATOM | 7940 | CD2 | PHE | G | 471 | −6.320 | 29.189 | 64.002 | 1.00 | 39.66 | G | C |
| ATOM | 7941 | CE1 | PHE | G | 471 | −6.629 | 27.436 | 66.136 | 1.00 | 42.44 | G | C |
| ATOM | 7942 | CE2 | PHE | G | 471 | −7.213 | 29.499 | 65.030 | 1.00 | 44.17 | G | C |
| ATOM | 7943 | CZ | PHE | G | 471 | −7.370 | 28.620 | 66.102 | 1.00 | 44.18 | G | C |
| ATOM | 7944 | C | PHE | G | 471 | −3.352 | 25.815 | 61.850 | 1.00 | 32.25 | G | C |
| ATOM | 7945 | O | PHE | G | 471 | −4.099 | 25.109 | 61.184 | 1.00 | 32.82 | G | O |
| ATOM | 7946 | N | LEU | G | 472 | −2.088 | 26.100 | 61.515 | 1.00 | 30.52 | G | N |
| ATOM | 7947 | CA | LEU | G | 472 | −1.457 | 25.640 | 60.268 | 1.00 | 31.48 | G | C |
| ATOM | 7948 | CB | LEU | G | 472 | −1.519 | 26.742 | 59.174 | 1.00 | 30.59 | G | C |
| ATOM | 7949 | CG | LEU | G | 472 | −2.836 | 27.446 | 58.831 | 1.00 | 27.17 | G | C |
| ATOM | 7950 | CD1 | LEU | G | 472 | −2.552 | 28.739 | 58.101 | 1.00 | 29.89 | G | C |
| ATOM | 7951 | CD2 | LEU | G | 472 | −3.681 | 26.541 | 57.975 | 1.00 | 25.65 | G | C |
| ATOM | 7952 | C | LEU | G | 472 | 0.017 | 25.271 | 60.472 | 1.00 | 29.62 | G | C |
| ATOM | 7953 | O | LEU | G | 472 | 0.692 | 25.825 | 61.343 | 1.00 | 31.16 | G | O |
| ATOM | 7954 | N | PRO | G | 473 | 0.534 | 24.328 | 59.664 | 1.00 | 27.20 | G | N |
| ATOM | 7955 | CD | PRO | G | 473 | −0.246 | 23.568 | 58.669 | 1.00 | 24.83 | G | C |
| ATOM | 7956 | CA | PRO | G | 473 | 1.929 | 23.869 | 59.718 | 1.00 | 26.19 | G | C |
| ATOM | 7957 | CB | PRO | G | 473 | 1.853 | 22.444 | 59.198 | 1.00 | 24.49 | G | C |
| ATOM | 7958 | CG | PRO | G | 473 | 0.695 | 22.451 | 58.261 | 1.00 | 22.63 | G | C |
| ATOM | 7959 | C | PRO | G | 473 | 2.911 | 24.703 | 58.876 | 1.00 | 29.22 | G | C |
| ATOM | 7960 | O | PRO | G | 473 | 4.105 | 24.816 | 59.213 | 1.00 | 27.75 | G | O |
| ATOM | 7961 | N | HIS | G | 474 | 2.410 | 25.270 | 57.776 | 1.00 | 27.28 | G | N |
| ATOM | 7962 | CA | HIS | G | 474 | 3.240 | 26.079 | 56.874 | 1.00 | 26.71 | G | C |
| ATOM | 7963 | CB | HIS | G | 474 | 4.134 | 25.160 | 56.042 | 1.00 | 22.13 | G | C |
| ATOM | 7964 | CG | HIS | G | 474 | 3.381 | 24.056 | 55.371 | 1.00 | 24.76 | G | C |
| ATOM | 7965 | CD2 | HIS | G | 474 | 2.366 | 24.090 | 54.475 | 1.00 | 26.27 | G | C |
| ATOM | 7966 | ND1 | HIS | G | 474 | 3.582 | 22.725 | 55.668 | 1.00 | 26.75 | G | N |
| ATOM | 7967 | CE1 | HIS | G | 474 | 2.722 | 21.987 | 54.987 | 1.00 | 25.69 | G | C |
| ATOM | 7968 | NE2 | HIS | G | 474 | 1.973 | 22.790 | 54.256 | 1.00 | 26.48 | G | N |
| ATOM | 7969 | C | HIS | G | 474 | 2.347 | 26.914 | 55.949 | 1.00 | 26.76 | G | C |
| ATOM | 7970 | O | HIS | G | 474 | 1.119 | 26.809 | 56.014 | 1.00 | 25.17 | G | O |
| ATOM | 7971 | N | PHE | G | 475 | 2.958 | 27.727 | 55.086 | 1.00 | 26.08 | G | N |
| ATOM | 7972 | CA | PHE | G | 475 | 2.189 | 28.581 | 54.176 | 1.00 | 23.68 | G | C |
| ATOM | 7973 | CB | PHE | G | 475 | 3.095 | 29.633 | 53.534 | 1.00 | 20.30 | G | C |
| ATOM | 7974 | CG | PHE | G | 475 | 2.335 | 30.753 | 52.876 | 1.00 | 24.50 | G | C |
| ATOM | 7975 | CD1 | PHE | G | 475 | 2.405 | 30.947 | 51.490 | 1.00 | 23.16 | G | C |
| ATOM | 7976 | CD2 | PHE | G | 475 | 1.547 | 31.621 | 53.639 | 1.00 | 22.49 | G | C |
| ATOM | 7977 | CE1 | PHE | G | 475 | 1.700 | 31.994 | 50.868 | 1.00 | 22.19 | G | C |
| ATOM | 7978 | CE2 | PHE | G | 475 | 0.838 | 32.670 | 53.033 | 1.00 | 21.86 | G | C |
| ATOM | 7979 | CZ | PHE | G | 475 | 0.920 | 32.854 | 51.634 | 1.00 | 21.93 | G | C |
| ATOM | 7980 | C | PHE | G | 475 | 1.434 | 27.821 | 53.090 | 1.00 | 20.59 | G | C |
| ATOM | 7981 | O | PHE | G | 475 | 0.364 | 28.237 | 52.665 | 1.00 | 20.67 | G | O |
| ATOM | 7982 | N | GLY | G | 476 | 1.996 | 26.702 | 52.649 | 1.00 | 23.28 | G | N |
| ATOM | 7983 | CA | GLY | G | 476 | 1.349 | 25.903 | 51.620 | 1.00 | 20.90 | G | C |
| ATOM | 7984 | C | GLY | G | 476 | −0.036 | 25.442 | 52.030 | 1.00 | 22.53 | G | C |
| ATOM | 7985 | O | GLY | G | 476 | −0.943 | 25.346 | 51.199 | 1.00 | 22.07 | G | O |
| ATOM | 7986 | N | LYS | G | 477 | −0.220 | 25.156 | 53.318 | 1.00 | 23.21 | G | N |
| ATOM | 7987 | CA | LYS | G | 477 | −1.523 | 24.703 | 53.797 | 1.00 | 19.79 | G | C |
| ATOM | 7988 | CB | LYS | G | 477 | −1.400 | 24.128 | 55.212 | 1.00 | 22.53 | G | C |
| ATOM | 7989 | CG | LYS | G | 477 | −2.702 | 23.536 | 55.764 | 1.00 | 23.77 | G | C |
| ATOM | 7990 | CD | LYS | G | 477 | −3.084 | 22.227 | 55.076 | 1.00 | 24.57 | G | C |
| ATOM | 7991 | CE | LYS | G | 477 | −4.557 | 21.919 | 55.278 | 1.00 | 28.05 | G | C |
| ATOM | 7992 | NZ | LYS | G | 477 | −4.930 | 20.563 | 54.803 | 1.00 | 30.53 | G | N |
| ATOM | 7993 | C | LYS | G | 477 | −2.554 | 25.825 | 53.770 | 1.00 | 18.96 | G | C |
| ATOM | 7994 | O | LYS | G | 477 | −3.750 | 25.571 | 53.640 | 1.00 | 20.17 | G | O |
| ATOM | 7995 | N | MET | G | 478 | −2.101 | 27.069 | 53.890 | 1.00 | 19.40 | G | N |
| ATOM | 7996 | CA | MET | G | 478 | −3.036 | 28.187 | 53.852 | 1.00 | 18.14 | G | C |
| ATOM | 7997 | CB | MET | G | 478 | −2.359 | 29.493 | 54.280 | 1.00 | 18.54 | G | C |
| ATOM | 7998 | CG | MET | G | 478 | −3.342 | 30.661 | 54.376 | 1.00 | 15.73 | G | C |
| ATOM | 7999 | SD | MET | G | 478 | −2.620 | 32.150 | 55.044 | 1.00 | 21.95 | G | S |
| ATOM | 8000 | CE | MET | G | 478 | −3.991 | 33.324 | 54.859 | 1.00 | 14.68 | G | C |
| ATOM | 8001 | C | MET | G | 478 | −3.535 | 28.336 | 52.421 | 1.00 | 18.21 | G | C |
| ATOM | 8002 | O | MET | G | 478 | −4.736 | 28.514 | 52.177 | 1.00 | 18.47 | G | O |
| ATOM | 8003 | N | LEU | G | 479 | −2.589 | 28.264 | 51.484 | 1.00 | 18.96 | G | N |
| ATOM | 8004 | CA | LEU | G | 479 | −2.881 | 28.391 | 50.072 | 1.00 | 16.03 | G | C |
| ATOM | 8005 | CB | LEU | G | 479 | −1.583 | 28.294 | 49.265 | 1.00 | 14.56 | G | C |
| ATOM | 8006 | CG | LEU | G | 479 | −0.667 | 29.530 | 49.279 | 1.00 | 9.63 | G | C |
| ATOM | 8007 | CD1 | LEU | G | 479 | 0.582 | 29.253 | 48.458 | 1.00 | 12.96 | G | C |
| ATOM | 8008 | CD2 | LEU | G | 479 | −1.387 | 30.717 | 48.693 | 1.00 | 11.08 | G | C |
| ATOM | 8009 | C | LEU | G | 479 | −3.841 | 27.273 | 49.707 | 1.00 | 18.82 | G | C |
| ATOM | 8010 | O | LEU | G | 479 | −4.812 | 27.483 | 48.970 | 1.00 | 17.06 | G | O |
| ATOM | 8011 | N | GLU | G | 480 | −3.590 | 26.082 | 50.244 | 1.00 | 20.61 | G | N |
| ATOM | 8012 | CA | GLU | G | 480 | −4.467 | 24.949 | 49.961 | 1.00 | 21.95 | G | C |
| ATOM | 8013 | CB | GLU | G | 480 | −3.905 | 23.658 | 50.566 | 1.00 | 23.03 | G | C |
| ATOM | 8014 | CG | GLU | G | 480 | −4.800 | 22.455 | 50.303 | 1.00 | 27.17 | G | C |
| ATOM | 8015 | CD | GLU | G | 480 | −4.123 | 21.133 | 50.611 | 1.00 | 31.57 | G | C |
| ATOM | 8016 | OE1 | GLU | G | 480 | −2.944 | 21.137 | 51.040 | 1.00 | 34.05 | G | O |
| ATOM | 8017 | OE2 | GLU | G | 480 | −4.774 | 20.085 | 50.419 | 1.00 | 34.42 | G | O |
| ATOM | 8018 | C | GLU | G | 480 | −5.894 | 25.169 | 50.467 | 1.00 | 20.26 | G | C |
| ATOM | 8019 | O | GLU | G | 480 | −6.858 | 24.849 | 49.772 | 1.00 | 22.22 | G | O |
| ATOM | 8020 | N | ASN | G | 481 | −6.040 | 25.709 | 51.670 | 1.00 | 18.09 | G | N |
| ATOM | 8021 | CA | ASN | G | 481 | −7.376 | 25.955 | 52.217 | 1.00 | 18.70 | G | C |
| ATOM | 8022 | CB | ASN | G | 481 | −7.293 | 26.395 | 53.680 | 1.00 | 20.82 | G | C |
| ATOM | 8023 | CG | ASN | G | 481 | −6.752 | 25.302 | 54.588 | 1.00 | 24.07 | G | C |
| ATOM | 8024 | OD1 | ASN | G | 481 | −6.173 | 25.580 | 55.636 | 1.00 | 23.28 | G | O |
| ATOM | 8025 | ND2 | ASN | G | 481 | −6.943 | 24.057 | 54.188 | 1.00 | 21.25 | G | N |
| ATOM | 8026 | C | ASN | G | 481 | −8.120 | 27.025 | 51.432 | 1.00 | 17.80 | G | C |
| ATOM | 8027 | O | ASN | G | 481 | −9.349 | 26.980 | 51.322 | 1.00 | 15.74 | G | O |
| ATOM | 8028 | N | VAL | G | 482 | −7.377 | 27.997 | 50.905 | 1.00 | 15.79 | G | N |
| ATOM | 8029 | CA | VAL | G | 482 | −7.987 | 29.069 | 50.135 | 1.00 | 16.02 | G | C |
| ATOM | 8030 | CB | VAL | G | 482 | −7.032 | 30.277 | 49.968 | 1.00 | 16.35 | G | C |
| ATOM | 8031 | CG1 | VAL | G | 482 | −7.705 | 31.344 | 49.104 | 1.00 | 13.51 | G | C |
| ATOM | 8032 | CG2 | VAL | G | 482 | −6.667 | 30.866 | 51.343 | 1.00 | 16.80 | G | C |
| ATOM | 8033 | C | VAL | G | 482 | −8.418 | 28.644 | 48.738 | 1.00 | 16.89 | G | C |
| ATOM | 8034 | O | VAL | G | 482 | −9.529 | 28.960 | 48.303 | 1.00 | 16.28 | G | O |
| ATOM | 8035 | N | PHE | G | 483 | −7.556 | 27.899 | 48.046 | 1.00 | 17.64 | G | N |
| ATOM | 8036 | CA | PHE | G | 483 | −7.846 | 27.520 | 46.663 | 1.00 | 18.43 | G | C |
| ATOM | 8037 | CB | PHE | G | 483 | −6.608 | 27.824 | 45.816 | 1.00 | 15.23 | G | C |
| ATOM | 8038 | CG | PHE | G | 483 | −6.282 | 29.298 | 45.735 | 1.00 | 14.92 | G | C |
| ATOM | 8039 | CD1 | PHE | G | 483 | −7.127 | 30.173 | 45.067 | 1.00 | 12.00 | G | C |
| ATOM | 8040 | CD2 | PHE | G | 483 | −5.140 | 29.806 | 46.338 | 1.00 | 15.04 | G | C |
| ATOM | 8041 | CE1 | PHE | G | 483 | −6.849 | 31.521 | 44.997 | 1.00 | 11.90 | G | C |
| ATOM | 8042 | CE2 | PHE | G | 483 | −4.849 | 31.165 | 46.273 | 1.00 | 16.56 | G | C |
| ATOM | 8043 | CZ | PHE | G | 483 | −5.706 | 32.022 | 45.601 | 1.00 | 13.96 | G | C |
| ATOM | 8044 | C | PHE | G | 483 | −8.380 | 26.134 | 46.302 | 1.00 | 19.16 | G | C |
| ATOM | 8045 | O | PHE | G | 483 | −9.223 | 26.015 | 45.427 | 1.00 | 20.62 | G | O |
| ATOM | 8046 | N | MET | G | 484 | −7.899 | 25.089 | 46.960 | 1.00 | 22.19 | G | N |
| ATOM | 8047 | CA | MET | G | 484 | −8.338 | 23.729 | 46.651 | 1.00 | 23.25 | G | C |
| ATOM | 8048 | CB | MET | G | 484 | −7.706 | 22.744 | 47.634 | 1.00 | 26.55 | G | C |
| ATOM | 8049 | CG | MET | G | 484 | −7.868 | 21.283 | 47.229 | 1.00 | 30.61 | G | C |
| ATOM | 8050 | SD | MET | G | 484 | −6.924 | 20.872 | 45.748 | 1.00 | 34.46 | G | S |
| ATOM | 8051 | CE | MET | G | 484 | −5.314 | 20.630 | 46.431 | 1.00 | 30.14 | G | C |
| ATOM | 8052 | C | MET | G | 484 | −9.851 | 23.490 | 46.609 | 1.00 | 23.86 | G | C |
| ATOM | 8053 | O | MET | G | 484 | −10.360 | 22.841 | 45.693 | 1.00 | 24.53 | G | O |
| ATOM | 8054 | N | PRO | G | 485 | −10.597 | 23.988 | 47.608 | 1.00 | 23.73 | G | N |
| ATOM | 8055 | CD | PRO | G | 485 | −10.212 | 24.746 | 48.809 | 1.00 | 21.00 | G | C |
| ATOM | 8056 | CA | PRO | G | 485 | −12.044 | 23.749 | 47.560 | 1.00 | 22.36 | G | C |
| ATOM | 8057 | CB | PRO | G | 485 | −12.558 | 24.381 | 48.855 | 1.00 | 20.64 | G | C |
| ATOM | 8058 | CG | PRO | G | 485 | −11.355 | 24.489 | 49.729 | 1.00 | 19.95 | G | C |
| ATOM | 8059 | C | PRO | G | 485 | −12.706 | 24.351 | 46.327 | 1.00 | 23.02 | G | C |
| ATOM | 8060 | O | PRO | G | 485 | −13.684 | 23.809 | 45.808 | 1.00 | 22.92 | G | O |
| ATOM | 8061 | N | VAL | G | 486 | −12.166 | 25.480 | 45.872 | 1.00 | 23.29 | G | N |
| ATOM | 8062 | CA | VAL | G | 486 | −12.695 | 26.171 | 44.705 | 1.00 | 21.08 | G | C |
| ATOM | 8063 | CB | VAL | G | 486 | −12.124 | 27.600 | 44.625 | 1.00 | 22.78 | G | C |
| ATOM | 8064 | CG1 | VAL | G | 486 | −12.652 | 28.295 | 43.406 | 1.00 | 25.45 | G | C |
| ATOM | 8065 | CG2 | VAL | G | 486 | −12.529 | 28.383 | 45.857 | 1.00 | 24.24 | G | C |
| ATOM | 8066 | C | VAL | G | 486 | −12.351 | 25.380 | 43.442 | 1.00 | 19.67 | G | C |
| ATOM | 8067 | O | VAL | G | 486 | −13.157 | 25.291 | 42.524 | 1.00 | 21.01 | G | O |
| ATOM | 8068 | N | PHE | G | 487 | −11.156 | 24.804 | 43.394 | 1.00 | 19.68 | G | N |
| ATOM | 8069 | CA | PHE | G | 487 | −10.761 | 23.998 | 42.246 | 1.00 | 21.87 | G | C |
| ATOM | 8070 | CB | PHE | G | 487 | −9.289 | 23.595 | 42.346 | 1.00 | 19.60 | G | C |
| ATOM | 8071 | CG | PHE | G | 487 | −8.349 | 24.562 | 41.693 | 1.00 | 21.77 | G | C |
| ATOM | 8072 | CD1 | PHE | G | 487 | −7.781 | 25.601 | 42.427 | 1.00 | 22.29 | G | C |
| ATOM | 8073 | CD2 | PHE | G | 487 | −8.000 | 24.425 | 40.349 | 1.00 | 23.13 | G | C |
| ATOM | 8074 | CE1 | PHE | G | 487 | −6.873 | 26.494 | 41.835 | 1.00 | 20.38 | G | C |
| ATOM | 8075 | CE2 | PHE | G | 487 | −7.095 | 25.309 | 39.750 | 1.00 | 20.95 | G | C |
| ATOM | 8076 | CZ | PHE | G | 487 | −6.531 | 26.343 | 40.498 | 1.00 | 20.77 | G | C |
| ATOM | 8077 | C | PHE | G | 487 | −11.634 | 22.738 | 42.245 | 1.00 | 25.61 | G | C |
| ATOM | 8078 | O | PHE | G | 487 | −12.045 | 22.253 | 41.193 | 1.00 | 26.77 | G | O |
| ATOM | 8079 | N | GLU | G | 488 | −11.930 | 22.217 | 43.433 | 1.00 | 25.98 | G | N |
| ATOM | 8080 | CA | GLU | G | 488 | −12.745 | 21.015 | 43.553 | 1.00 | 24.73 | G | C |
| ATOM | 8081 | CB | GLU | G | 488 | −12.811 | 20.551 | 45.004 | 1.00 | 28.33 | G | C |
| ATOM | 8082 | CG | GLU | G | 488 | −11.974 | 19.329 | 45.282 | 1.00 | 35.27 | G | C |
| ATOM | 8083 | CD | GLU | G | 488 | −11.502 | 19.288 | 46.719 | 1.00 | 42.14 | G | C |
| ATOM | 8084 | OE1 | GLU | G | 488 | −12.242 | 19.808 | 47.595 | 1.00 | 42.44 | G | O |
| ATOM | 8085 | OE2 | GLU | G | 488 | −10.397 | 18.740 | 46.971 | 1.00 | 44.17 | G | O |
| ATOM | 8086 | C | GLU | G | 488 | −14.152 | 21.236 | 43.061 | 1.00 | 24.15 | G | C |
| ATOM | 8087 | O | GLU | G | 488 | −14.744 | 20.354 | 42.442 | 1.00 | 24.30 | G | O |
| ATOM | 8088 | N | ALA | G | 489 | −14.709 | 22.406 | 43.347 | 1.00 | 21.95 | G | N |
| ATOM | 8089 | CA | ALA | G | 489 | −16.066 | 22.688 | 42.905 | 1.00 | 20.75 | G | C |
| ATOM | 8090 | CB | ALA | G | 489 | −16.623 | 23.912 | 43.646 | 1.00 | 15.76 | G | C |
| ATOM | 8091 | C | ALA | G | 489 | −16.101 | 22.912 | 41.382 | 1.00 | 22.88 | G | C |
| ATOM | 8092 | O | ALA | G | 489 | −17.122 | 22.663 | 40.735 | 1.00 | 23.26 | G | O |
| ATOM | 8093 | N | THR | G | 490 | −14.985 | 23.372 | 40.818 | 1.00 | 22.58 | G | N |
| ATOM | 8094 | CA | THR | G | 490 | −14.888 | 23.640 | 39.380 | 1.00 | 25.36 | G | C |
| ATOM | 8095 | CB | THR | G | 490 | −13.603 | 24.464 | 39.062 | 1.00 | 25.24 | G | C |
| ATOM | 8096 | OG1 | THR | G | 490 | −13.736 | 25.780 | 39.617 | 1.00 | 25.31 | G | O |
| ATOM | 8097 | CG2 | THR | G | 490 | −13.371 | 24.581 | 37.558 | 1.00 | 22.51 | G | C |
| ATOM | 8098 | C | THR | G | 490 | −14.868 | 22.317 | 38.606 | 1.00 | 26.49 | G | C |
| ATOM | 8099 | O | THR | G | 490 | −15.607 | 22.134 | 37.641 | 1.00 | 25.39 | G | O |
| ATOM | 8100 | N | ILE | G | 491 | −14.034 | 21.394 | 39.070 | 1.00 | 27.46 | G | N |
| ATOM | 8101 | CA | ILE | G | 491 | −13.873 | 20.081 | 38.474 | 1.00 | 26.38 | G | C |
| ATOM | 8102 | CB | ILE | G | 491 | −12.602 | 19.428 | 39.076 | 1.00 | 28.07 | G | C |
| ATOM | 8103 | CG2 | ILE | G | 491 | −12.916 | 18.150 | 39.826 | 1.00 | 31.48 | G | C |
| ATOM | 8104 | CG1 | ILE | G | 491 | −11.594 | 19.212 | 37.966 | 1.00 | 28.85 | G | C |
| ATOM | 8105 | CD1 | ILE | G | 491 | −10.543 | 20.270 | 37.954 | 1.00 | 32.09 | G | C |
| ATOM | 8106 | C | ILE | G | 491 | −15.122 | 19.205 | 38.666 | 1.00 | 26.65 | G | C |
| ATOM | 8107 | O | ILE | G | 491 | −15.529 | 18.486 | 37.748 | 1.00 | 24.99 | G | O |
| ATOM | 8108 | N | ASN | G | 492 | −15.745 | 19.297 | 39.844 | 1.00 | 26.49 | G | N |
| ATOM | 8109 | CA | ASN | G | 492 | −16.945 | 18.522 | 40.165 | 1.00 | 24.14 | G | C |
| ATOM | 8110 | CB | ASN | G | 492 | −16.621 | 17.455 | 41.197 | 1.00 | 25.85 | G | C |
| ATOM | 8111 | CG | ASN | G | 492 | −15.543 | 16.514 | 40.728 | 1.00 | 27.17 | G | C |
| ATOM | 8112 | OD1 | ASN | G | 492 | −15.611 | 15.983 | 39.620 | 1.00 | 26.01 | G | O |
| ATOM | 8113 | ND2 | ASN | G | 492 | −14.534 | 16.304 | 41.566 | 1.00 | 27.87 | G | N |
| ATOM | 8114 | C | ASN | G | 492 | −18.058 | 19.389 | 40.707 | 1.00 | 23.94 | G | C |
| ATOM | 8115 | O | ASN | G | 492 | −18.398 | 19.303 | 41.882 | 1.00 | 25.04 | G | O |
| ATOM | 8116 | N | PRO | G | 493 | −18.677 | 20.202 | 39.844 | 1.00 | 25.40 | G | N |
| ATOM | 8117 | CD | PRO | G | 493 | −18.408 | 20.309 | 38.397 | 1.00 | 25.51 | G | C |
| ATOM | 8118 | CA | PRO | G | 493 | −19.760 | 21.092 | 40.268 | 1.00 | 25.62 | G | C |
| ATOM | 8119 | CB | PRO | G | 493 | −20.173 | 21.810 | 38.974 | 1.00 | 24.77 | G | C |
| ATOM | 8120 | CG | PRO | G | 493 | −19.016 | 21.628 | 38.036 | 1.00 | 23.21 | G | C |
| ATOM | 8121 | C | PRO | G | 493 | −20.938 | 20.387 | 40.910 | 1.00 | 26.06 | G | C |
| ATOM | 8122 | O | PRO | G | 493 | −21.569 | 20.909 | 41.823 | 1.00 | 26.47 | G | O |
| ATOM | 8123 | N | GLN | G | 494 | −21.249 | 19.204 | 40.410 | 1.00 | 27.07 | G | N |
| ATOM | 8124 | CA | GLN | G | 494 | −22.382 | 18.449 | 40.918 | 1.00 | 29.16 | G | C |
| ATOM | 8125 | CB | GLN | G | 494 | −22.654 | 17.272 | 39.992 | 1.00 | 33.51 | G | C |
| ATOM | 8126 | CG | GLN | G | 494 | −22.816 | 17.703 | 38.553 | 1.00 | 37.99 | G | C |
| ATOM | 8127 | CD | GLN | G | 494 | −24.233 | 18.132 | 38.237 | 1.00 | 39.53 | G | C |
| ATOM | 8128 | OE1 | GLN | G | 494 | −24.799 | 17.719 | 37.232 | 1.00 | 47.93 | G | O |
| ATOM | 8129 | NE2 | GLN | G | 494 | −24.814 | 18.958 | 39.094 | 1.00 | 40.52 | G | N |
| ATOM | 8130 | C | GLN | G | 494 | −22.186 | 17.957 | 42.344 | 1.00 | 28.63 | G | C |
| ATOM | 8131 | O | GLN | G | 494 | −23.156 | 17.805 | 43.093 | 1.00 | 25.02 | G | O |
| ATOM | 8132 | N | ALA | G | 495 | −20.928 | 17.703 | 42.702 | 1.00 | 26.38 | G | N |
| ATOM | 8133 | CA | ALA | G | 495 | −20.577 | 17.245 | 44.031 | 1.00 | 23.16 | G | C |
| ATOM | 8134 | CB | ALA | G | 495 | −19.180 | 16.646 | 44.012 | 1.00 | 22.34 | G | C |
| ATOM | 8135 | C | ALA | G | 495 | −20.643 | 18.415 | 45.015 | 1.00 | 25.05 | G | C |
| ATOM | 8136 | O | ALA | G | 495 | −20.869 | 18.210 | 46.206 | 1.00 | 25.36 | G | O |
| ATOM | 8137 | N | HIS | G | 496 | −20.466 | 19.640 | 44.513 | 1.00 | 24.57 | G | N |
| ATOM | 8138 | CA | HIS | G | 496 | −20.495 | 20.852 | 45.342 | 1.00 | 21.89 | G | C |
| ATOM | 8139 | CB | HIS | G | 496 | −19.091 | 21.414 | 45.466 | 1.00 | 22.82 | G | C |
| ATOM | 8140 | CG | HIS | G | 496 | −18.051 | 20.369 | 45.706 | 1.00 | 25.05 | G | C |
| ATOM | 8141 | CD2 | HIS | G | 496 | −17.181 | 19.765 | 44.861 | 1.00 | 27.37 | G | C |
| ATOM | 8142 | ND1 | HIS | G | 496 | −17.806 | 19.839 | 46.955 | 1.00 | 26.23 | G | N |
| ATOM | 8143 | CE1 | HIS | G | 496 | −16.829 | 18.953 | 46.869 | 1.00 | 27.18 | G | C |
| ATOM | 8144 | NE2 | HIS | G | 496 | −16.432 | 18.888 | 45.610 | 1.00 | 29.20 | G | N |
| ATOM | 8145 | C | HIS | G | 496 | −21.410 | 21.906 | 44.735 | 1.00 | 22.77 | G | C |
| ATOM | 8146 | O | HIS | G | 496 | −20.970 | 22.970 | 44.312 | 1.00 | 22.86 | G | O |
| ATOM | 8147 | N | PRO | G | 497 | −22.713 | 21.632 | 44.723 | 1.00 | 23.45 | G | N |
| ATOM | 8148 | CD | PRO | G | 497 | −23.316 | 20.415 | 45.297 | 1.00 | 21.76 | G | C |
| ATOM | 8149 | CA | PRO | G | 497 | −23.715 | 22.542 | 44.158 | 1.00 | 23.46 | G | C |
| ATOM | 8150 | CB | PRO | G | 497 | −25.016 | 21.749 | 44.248 | 1.00 | 21.23 | G | C |
| ATOM | 8151 | CG | PRO | G | 497 | −24.772 | 20.748 | 45.335 | 1.00 | 22.69 | G | C |
| ATOM | 8152 | C | PRO | G | 497 | −23.845 | 23.916 | 44.799 | 1.00 | 26.15 | G | C |
| ATOM | 8153 | O | PRO | G | 497 | −23.987 | 24.919 | 44.095 | 1.00 | 26.48 | G | O |
| ATOM | 8154 | N | GLU | G | 498 | −23.826 | 23.972 | 46.129 | 1.00 | 25.17 | G | N |
| ATOM | 8155 | CA | GLU | G | 498 | −23.953 | 25.250 | 46.815 | 1.00 | 22.22 | G | C |
| ATOM | 8156 | CB | GLU | G | 498 | −24.166 | 25.042 | 48.312 | 1.00 | 24.14 | G | C |
| ATOM | 8157 | CG | GLU | G | 498 | −25.624 | 25.013 | 48.692 | 1.00 | 22.63 | G | C |
| ATOM | 8158 | CD | GLU | G | 498 | −25.878 | 25.308 | 50.162 | 1.00 | 27.63 | G | C |
| ATOM | 8159 | OE1 | GLU | G | 498 | −25.028 | 24.972 | 51.016 | 1.00 | 26.18 | G | O |
| ATOM | 8160 | OE2 | GLU | G | 498 | −26.946 | 25.878 | 50.460 | 1.00 | 28.27 | G | O |
| ATOM | 8161 | C | GLU | G | 498 | −22.717 | 26.099 | 46.581 | 1.00 | 20.01 | G | C |
| ATOM | 8162 | O | GLU | G | 498 | −22.824 | 27.286 | 46.295 | 1.00 | 20.99 | G | O |
| ATOM | 8163 | N | LEU | G | 499 | −21.543 | 25.494 | 46.710 | 1.00 | 19.46 | G | N |
| ATOM | 8164 | CA | LEU | G | 499 | −20.305 | 26.225 | 46.466 | 1.00 | 20.31 | G | C |
| ATOM | 8165 | CB | LEU | G | 499 | −19.084 | 25.359 | 46.814 | 1.00 | 17.15 | G | C |
| ATOM | 8166 | CG | LEU | G | 499 | −17.733 | 26.046 | 46.618 | 1.00 | 16.66 | G | C |
| ATOM | 8167 | CD1 | LEU | G | 499 | −17.786 | 27.432 | 47.233 | 1.00 | 18.18 | G | C |
| ATOM | 8168 | CD2 | LEU | G | 499 | −16.628 | 25.221 | 47.224 | 1.00 | 16.69 | G | C |
| ATOM | 8169 | C | LEU | G | 499 | −20.241 | 26.658 | 44.991 | 1.00 | 20.41 | G | C |
| ATOM | 8170 | O | LEU | G | 499 | −19.803 | 27.761 | 44.677 | 1.00 | 22.75 | G | O |
| ATOM | 8171 | N | SER | G | 500 | −20.695 | 25.790 | 44.095 | 1.00 | 19.72 | G | N |
| ATOM | 8172 | CA | SER | G | 500 | −20.683 | 26.088 | 42.664 | 1.00 | 19.14 | G | C |
| ATOM | 8173 | CB | SER | G | 500 | −21.170 | 24.873 | 41.857 | 1.00 | 19.22 | G | C |
| ATOM | 8174 | OG | SER | G | 500 | −20.214 | 23.825 | 41.894 | 1.00 | 16.28 | G | O |
| ATOM | 8175 | C | SER | G | 500 | −21.552 | 27.295 | 42.336 | 1.00 | 18.45 | G | C |
| ATOM | 8176 | O | SER | G | 500 | −21.190 | 28.115 | 41.492 | 1.00 | 17.85 | G | O |
| ATOM | 8177 | N | VAL | G | 501 | −22.700 | 27.402 | 42.996 | 1.00 | 15.87 | G | N |
| ATOM | 8178 | CA | VAL | G | 501 | −23.601 | 28.530 | 42.761 | 1.00 | 16.89 | G | C |
| ATOM | 8179 | CB | VAL | G | 501 | −24.996 | 28.274 | 43.403 | 1.00 | 17.04 | G | C |
| ATOM | 8180 | CG1 | VAL | G | 501 | −25.737 | 29.583 | 43.591 | 1.00 | 15.30 | G | C |
| ATOM | 8181 | CG2 | VAL | G | 501 | −25.805 | 27.337 | 42.533 | 1.00 | 10.62 | G | C |
| ATOM | 8182 | C | VAL | G | 501 | −23.005 | 29.828 | 43.327 | 1.00 | 18.39 | G | C |
| ATOM | 8183 | O | VAL | G | 501 | −23.054 | 30.885 | 42.691 | 1.00 | 18.34 | G | O |
| ATOM | 8184 | N | PHE | G | 502 | −22.443 | 29.739 | 44.528 | 1.00 | 17.84 | G | N |
| ATOM | 8185 | CA | PHE | G | 502 | −21.818 | 30.881 | 45.178 | 1.00 | 16.22 | G | C |
| ATOM | 8186 | CB | PHE | G | 502 | −21.255 | 30.422 | 46.536 | 1.00 | 18.48 | G | C |
| ATOM | 8187 | CG | PHE | G | 502 | −20.477 | 31.480 | 47.296 | 1.00 | 17.05 | G | C |
| ATOM | 8188 | CD1 | PHE | G | 502 | −21.053 | 32.709 | 47.606 | 1.00 | 14.59 | G | C |
| ATOM | 8189 | CD2 | PHE | G | 502 | −19.187 | 31.217 | 47.748 | 1.00 | 17.07 | G | C |
| ATOM | 8190 | CE1 | PHE | G | 502 | −20.358 | 33.658 | 48.358 | 1.00 | 16.16 | G | C |
| ATOM | 8191 | CE2 | PHE | G | 502 | −18.481 | 32.161 | 48.502 | 1.00 | 19.16 | G | C |
| ATOM | 8192 | CZ | PHE | G | 502 | −19.072 | 33.388 | 48.808 | 1.00 | 16.23 | G | C |
| ATOM | 8193 | C | PHE | G | 502 | −20.695 | 31.405 | 44.279 | 1.00 | 16.06 | G | C |
| ATOM | 8194 | O | PHE | G | 502 | −20.580 | 32.608 | 44.049 | 1.00 | 16.00 | G | O |
| ATOM | 8195 | N | LEU | G | 503 | −19.876 | 30.494 | 43.760 | 1.00 | 16.39 | G | N |
| ATOM | 8196 | CA | LEU | G | 503 | −18.753 | 30.881 | 42.910 | 1.00 | 15.97 | G | C |
| ATOM | 8197 | CB | LEU | G | 503 | −17.971 | 29.637 | 42.480 | 1.00 | 13.04 | G | C |
| ATOM | 8198 | CG | LEU | G | 503 | −17.058 | 29.089 | 43.589 | 1.00 | 14.56 | G | C |
| ATOM | 8199 | CD1 | LEU | G | 503 | −16.378 | 27.818 | 43.134 | 1.00 | 12.75 | G | C |
| ATOM | 8200 | CD2 | LEU | G | 503 | −16.011 | 30.135 | 43.971 | 1.00 | 14.01 | G | C |
| ATOM | 8201 | C | LEU | G | 503 | −19.172 | 31.713 | 41.694 | 1.00 | 16.81 | G | C |
| ATOM | 8202 | O | LEU | G | 503 | −18.376 | 32.498 | 41.168 | 1.00 | 17.20 | G | O |
| ATOM | 8203 | N | LYS | G | 504 | −20.417 | 31.543 | 41.258 | 1.00 | 14.41 | G | N |
| ATOM | 8204 | CA | LYS | G | 504 | −20.947 | 32.299 | 40.126 | 1.00 | 17.06 | G | C |
| ATOM | 8205 | CB | LYS | G | 504 | −22.253 | 31.680 | 39.622 | 1.00 | 16.35 | G | C |
| ATOM | 8206 | CG | LYS | G | 504 | −22.064 | 30.354 | 38.924 | 1.00 | 18.07 | G | C |
| ATOM | 8207 | CD | LYS | G | 504 | −23.387 | 29.710 | 38.634 | 1.00 | 22.21 | G | C |
| ATOM | 8208 | CE | LYS | G | 504 | −24.111 | 30.395 | 37.481 | 1.00 | 22.11 | G | C |
| ATOM | 8209 | NZ | LYS | G | 504 | −25.547 | 29.990 | 37.433 | 1.00 | 26.90 | G | N |
| ATOM | 8210 | C | LYS | G | 504 | −21.221 | 33.741 | 40.539 | 1.00 | 17.95 | G | C |
| ATOM | 8211 | O | LYS | G | 504 | −21.365 | 34.610 | 39.690 | 1.00 | 17.84 | G | O |
| ATOM | 8212 | N | HIS | G | 505 | −21.305 | 33.985 | 41.849 | 1.00 | 18.43 | G | N |
| ATOM | 8213 | CA | HIS | G | 505 | −21.566 | 35.324 | 42.367 | 1.00 | 14.35 | G | C |
| ATOM | 8214 | CB | HIS | G | 505 | −22.521 | 35.262 | 43.545 | 1.00 | 14.15 | G | C |
| ATOM | 8215 | CG | HIS | G | 505 | −23.890 | 34.796 | 43.182 | 1.00 | 15.11 | G | C |
| ATOM | 8216 | CD2 | HIS | G | 505 | −24.359 | 33.563 | 42.875 | 1.00 | 18.24 | G | C |
| ATOM | 8217 | ND1 | HIS | G | 505 | −24.980 | 35.638 | 43.152 | 1.00 | 16.98 | G | N |
| ATOM | 8218 | CE1 | HIS | G | 505 | −26.062 | 34.944 | 42.845 | 1.00 | 17.26 | G | C |
| ATOM | 8219 | NE2 | HIS | G | 505 | −25.714 | 33.681 | 42.673 | 1.00 | 16.20 | G | N |
| ATOM | 8220 | C | HIS | G | 505 | −20.304 | 36.046 | 42.803 | 1.00 | 14.08 | G | C |
| ATOM | 8221 | O | HIS | G | 505 | −20.378 | 37.194 | 43.215 | 1.00 | 14.81 | G | O |
| ATOM | 8222 | N | ILE | G | 506 | −19.156 | 35.375 | 42.722 | 1.00 | 13.29 | G | N |
| ATOM | 8223 | CA | ILE | G | 506 | −17.882 | 35.974 | 43.094 | 1.00 | 12.32 | G | C |
| ATOM | 8224 | CB | ILE | G | 506 | −16.941 | 34.946 | 43.738 | 1.00 | 9.31 | G | C |
| ATOM | 8225 | CG2 | ILE | G | 506 | −15.572 | 35.572 | 43.980 | 1.00 | 6.50 | G | C |
| ATOM | 8226 | CG1 | ILE | G | 506 | −17.540 | 34.438 | 45.047 | 1.00 | 9.19 | G | C |
| ATOM | 8227 | CD1 | ILE | G | 506 | −18.271 | 35.522 | 45.879 | 1.00 | 8.87 | G | C |
| ATOM | 8228 | C | ILE | G | 506 | −17.200 | 36.527 | 41.836 | 1.00 | 16.69 | G | C |
| ATOM | 8229 | O | ILE | G | 506 | −17.031 | 35.795 | 40.841 | 1.00 | 17.70 | G | O |
| ATOM | 8230 | N | THR | G | 507 | −16.810 | 37.804 | 41.882 | 1.00 | 13.51 | G | N |
| ATOM | 8231 | CA | THR | G | 507 | −16.167 | 38.460 | 40.749 | 1.00 | 14.24 | G | C |
| ATOM | 8232 | CB | THR | G | 507 | −16.750 | 39.882 | 40.515 | 1.00 | 11.41 | G | C |
| ATOM | 8233 | OG1 | THR | G | 507 | −16.302 | 40.767 | 41.546 | 1.00 | 13.73 | G | O |
| ATOM | 8234 | CG2 | THR | G | 507 | −18.269 | 39.848 | 40.516 | 1.00 | 8.67 | G | C |
| ATOM | 8235 | C | THR | G | 507 | −14.638 | 38.572 | 40.844 | 1.00 | 14.89 | G | C |
| ATOM | 8236 | O | THR | G | 507 | −13.971 | 38.746 | 39.826 | 1.00 | 14.97 | G | O |
| ATOM | 8237 | N | GLY | G | 508 | −14.081 | 38.474 | 42.053 | 1.00 | 12.88 | G | N |
| ATOM | 8238 | CA | GLY | G | 508 | −12.642 | 38.594 | 42.194 | 1.00 | 11.45 | G | C |
| ATOM | 8239 | C | GLY | G | 508 | −12.155 | 38.375 | 43.608 | 1.00 | 13.16 | G | C |
| ATOM | 8240 | O | GLY | G | 508 | −12.958 | 38.206 | 44.535 | 1.00 | 13.04 | G | O |
| ATOM | 8241 | N | PHE | G | 509 | −10.833 | 38.366 | 43.765 | 1.00 | 14.94 | G | N |
| ATOM | 8242 | CA | PHE | G | 509 | −10.179 | 38.176 | 45.063 | 1.00 | 14.07 | G | C |
| ATOM | 8243 | CB | PHE | G | 509 | −9.176 | 37.031 | 45.005 | 1.00 | 13.75 | G | C |
| ATOM | 8244 | CG | PHE | G | 509 | −9.803 | 35.689 | 44.869 | 1.00 | 14.53 | G | C |
| ATOM | 8245 | CD1 | PHE | G | 509 | −9.984 | 34.889 | 45.987 | 1.00 | 15.15 | G | C |
| ATOM | 8246 | CD2 | PHE | G | 509 | −10.216 | 35.222 | 43.626 | 1.00 | 14.50 | G | C |
| ATOM | 8247 | CE1 | PHE | G | 509 | −10.572 | 33.633 | 45.878 | 1.00 | 16.51 | G | C |
| ATOM | 8248 | CE2 | PHE | G | 509 | −10.803 | 33.974 | 43.501 | 1.00 | 19.22 | G | C |
| ATOM | 8249 | CZ | PHE | G | 509 | −10.984 | 33.172 | 44.637 | 1.00 | 17.42 | G | C |
| ATOM | 8250 | C | PHE | G | 509 | −9.415 | 39.424 | 45.461 | 1.00 | 16.55 | G | C |
| ATOM | 8251 | O | PHE | G | 509 | −8.824 | 40.105 | 44.611 | 1.00 | 15.23 | G | O |
| ATOM | 8252 | N | ASP | G | 510 | −9.412 | 39.700 | 46.764 | 1.00 | 18.05 | G | N |
| ATOM | 8253 | CA | ASP | G | 510 | −8.721 | 40.850 | 47.339 | 1.00 | 15.30 | G | C |
| ATOM | 8254 | CB | ASP | G | 510 | −9.748 | 41.749 | 48.042 | 1.00 | 13.21 | G | C |
| ATOM | 8255 | CG | ASP | G | 510 | −9.247 | 43.173 | 48.277 | 1.00 | 13.54 | G | C |
| ATOM | 8256 | OD1 | ASP | G | 510 | −8.028 | 43.392 | 48.386 | 1.00 | 16.16 | G | O |
| ATOM | 8257 | OD2 | ASP | G | 510 | −10.086 | 44.092 | 48.365 | 1.00 | 14.58 | G | O |
| ATOM | 8258 | C | ASP | G | 510 | −7.689 | 40.293 | 48.347 | 1.00 | 17.49 | G | C |
| ATOM | 8259 | O | ASP | G | 510 | −7.775 | 39.133 | 48.771 | 1.00 | 14.48 | G | O |
| ATOM | 8260 | N | SER | G | 511 | −6.694 | 41.104 | 48.686 | 1.00 | 16.54 | G | N |
| ATOM | 8261 | CA | SER | G | 511 | −5.680 | 40.723 | 49.656 | 1.00 | 15.45 | G | C |
| ATOM | 8262 | CB | SER | G | 511 | −4.326 | 40.548 | 48.990 | 1.00 | 16.38 | G | C |
| ATOM | 8263 | OG | SER | G | 511 | −3.350 | 40.162 | 49.949 | 1.00 | 13.27 | G | O |
| ATOM | 8264 | C | SER | G | 511 | −5.634 | 41.892 | 50.637 | 1.00 | 17.35 | G | C |
| ATOM | 8265 | O | SER | G | 511 | −5.477 | 43.044 | 50.227 | 1.00 | 14.83 | G | O |
| ATOM | 8266 | N | VAL | G | 512 | −5.776 | 41.592 | 51.927 | 1.00 | 18.22 | G | N |
| ATOM | 8267 | CA | VAL | G | 512 | −5.818 | 42.631 | 52.955 | 1.00 | 18.30 | G | C |
| ATOM | 8268 | CB | VAL | G | 512 | −7.276 | 42.858 | 53.432 | 1.00 | 16.61 | G | C |
| ATOM | 8269 | CG1 | VAL | G | 512 | −8.122 | 43.453 | 52.312 | 1.00 | 19.04 | G | C |
| ATOM | 8270 | CG2 | VAL | G | 512 | −7.869 | 41.552 | 53.877 | 1.00 | 17.12 | G | C |
| ATOM | 8271 | C | VAL | G | 512 | −4.937 | 42.380 | 54.191 | 1.00 | 19.30 | G | C |
| ATOM | 8272 | O | VAL | G | 512 | −4.658 | 41.242 | 54.555 | 1.00 | 15.39 | G | O |
| ATOM | 8273 | N | ASP | G | 513 | −4.513 | 43.482 | 54.813 | 1.00 | 21.73 | G | N |
| ATOM | 8274 | CA | ASP | G | 513 | −3.672 | 43.508 | 56.011 | 1.00 | 23.22 | G | C |
| ATOM | 8275 | CB | ASP | G | 513 | −2.512 | 42.502 | 55.919 | 1.00 | 27.01 | G | C |
| ATOM | 8276 | CG | ASP | G | 513 | −1.908 | 42.160 | 57.300 | 1.00 | 30.59 | G | C |
| ATOM | 8277 | OD1 | ASP | G | 513 | −2.577 | 42.406 | 58.336 | 1.00 | 30.16 | G | O |
| ATOM | 8278 | OD2 | ASP | G | 513 | −0.768 | 41.640 | 57.347 | 1.00 | 29.75 | G | O |
| ATOM | 8279 | C | ASP | G | 513 | −3.081 | 44.905 | 56.170 | 1.00 | 23.92 | G | C |
| ATOM | 8280 | O | ASP | G | 513 | −3.278 | 45.779 | 55.326 | 1.00 | 24.63 | G | O |
| ATOM | 8281 | N | ASP | G | 514 | −2.360 | 45.104 | 57.267 | 1.00 | 23.88 | G | N |
| ATOM | 8282 | CA | ASP | G | 514 | −1.703 | 46.368 | 57.551 | 1.00 | 24.90 | G | C |
| ATOM | 8283 | CB | ASP | G | 514 | −1.176 | 46.357 | 58.984 | 1.00 | 27.49 | G | C |
| ATOM | 8284 | CG | ASP | G | 514 | −0.511 | 47.664 | 59.383 | 1.00 | 31.00 | G | C |
| ATOM | 8285 | OD1 | ASP | G | 514 | −0.240 | 48.517 | 58.507 | 1.00 | 30.84 | G | O |
| ATOM | 8286 | OD2 | ASP | G | 514 | −0.256 | 47.832 | 60.596 | 1.00 | 36.33 | G | O |
| ATOM | 8287 | C | ASP | G | 514 | −0.549 | 46.416 | 56.567 | 1.00 | 24.72 | G | C |
| ATOM | 8288 | O | ASP | G | 514 | 0.446 | 45.709 | 56.740 | 1.00 | 25.15 | G | O |
| ATOM | 8289 | N | GLU | G | 515 | −0.680 | 47.240 | 55.534 | 1.00 | 24.08 | G | N |
| ATOM | 8290 | CA | GLU | G | 515 | 0.361 | 47.339 | 54.506 | 1.00 | 25.21 | G | C |
| ATOM | 8291 | CB | GLU | G | 515 | −0.189 | 48.074 | 53.283 | 1.00 | 23.90 | G | C |
| ATOM | 8292 | CG | GLU | G | 515 | 0.208 | 47.426 | 51.987 | 1.00 | 19.87 | G | C |
| ATOM | 8293 | CD | GLU | G | 515 | −0.204 | 48.241 | 50.796 | 1.00 | 20.34 | G | C |
| ATOM | 8294 | OE1 | GLU | G | 515 | −1.304 | 48.846 | 50.839 | 1.00 | 16.58 | G | O |
| ATOM | 8295 | OE2 | GLU | G | 515 | 0.577 | 48.277 | 49.822 | 1.00 | 19.99 | G | O |
| ATOM | 8296 | C | GLU | G | 515 | 1.661 | 48.000 | 54.947 | 1.00 | 24.78 | G | C |
| ATOM | 8297 | O | GLU | G | 515 | 2.697 | 47.854 | 54.286 | 1.00 | 23.65 | G | O |
| ATOM | 8298 | N | SER | G | 516 | 1.600 | 48.731 | 56.058 | 1.00 | 26.10 | G | N |
| ATOM | 8299 | CA | SER | G | 516 | 2.764 | 49.430 | 56.578 | 1.00 | 28.07 | G | C |
| ATOM | 8300 | CB | SER | G | 516 | 2.345 | 50.541 | 57.535 | 1.00 | 27.44 | G | C |
| ATOM | 8301 | OG | SER | G | 516 | 1.945 | 49.988 | 58.768 | 1.00 | 25.11 | G | O |
| ATOM | 8302 | C | SER | G | 516 | 3.666 | 48.469 | 57.301 | 1.00 | 30.67 | G | C |
| ATOM | 8303 | O | SER | G | 516 | 4.772 | 48.829 | 57.683 | 1.00 | 35.16 | G | O |
| ATOM | 8304 | N | LYS | G | 517 | 3.196 | 47.244 | 57.490 | 1.00 | 33.64 | G | N |
| ATOM | 8305 | CA | LYS | G | 517 | 3.988 | 46.237 | 58.169 | 1.00 | 37.29 | G | C |
| ATOM | 8306 | CB | LYS | G | 517 | 3.244 | 44.921 | 58.218 | 1.00 | 35.70 | G | C |
| ATOM | 8307 | CG | LYS | G | 517 | 3.102 | 44.372 | 59.604 | 1.00 | 37.04 | G | C |
| ATOM | 8308 | CD | LYS | G | 517 | 1.640 | 44.219 | 59.973 | 1.00 | 38.01 | G | C |
| ATOM | 8309 | CE | LYS | G | 517 | 0.960 | 43.175 | 59.102 | 1.00 | 38.13 | G | C |
| ATOM | 8310 | NZ | LYS | G | 517 | 0.985 | 41.808 | 59.696 | 1.00 | 40.22 | G | N |
| ATOM | 8311 | C | LYS | G | 517 | 5.354 | 46.000 | 57.542 | 1.00 | 44.42 | G | C |
| ATOM | 8312 | O | LYS | G | 517 | 5.607 | 46.316 | 56.369 | 1.00 | 47.00 | G | O |
| ATOM | 8313 | N | HIS | G | 518 | 6.217 | 45.418 | 58.361 | 1.00 | 49.90 | G | N |
| ATOM | 8314 | CA | HIS | G | 518 | 7.606 | 45.089 | 58.045 | 1.00 | 54.49 | G | C |
| ATOM | 8315 | CB | HIS | G | 518 | 8.402 | 45.162 | 59.334 | 1.00 | 59.41 | G | C |
| ATOM | 8316 | CG | HIS | G | 518 | 7.804 | 44.316 | 60.415 | 1.00 | 65.65 | G | C |
| ATOM | 8317 | CD2 | HIS | G | 518 | 6.738 | 44.533 | 61.228 | 1.00 | 67.09 | G | C |
| ATOM | 8318 | ND1 | HIS | G | 518 | 8.198 | 43.012 | 60.642 | 1.00 | 67.96 | G | N |
| ATOM | 8319 | CE1 | HIS | G | 518 | 7.402 | 42.464 | 61.543 | 1.00 | 69.08 | G | C |
| ATOM | 8320 | NE2 | HIS | G | 518 | 6.505 | 43.365 | 61.915 | 1.00 | 69.65 | G | N |
| ATOM | 8321 | C | HIS | G | 518 | 7.683 | 43.645 | 57.553 | 1.00 | 54.70 | G | C |
| ATOM | 8322 | O | HIS | G | 518 | 7.146 | 42.731 | 58.197 | 1.00 | 54.54 | G | O |
| ATOM | 8323 | N | SER | G | 519 | 8.354 | 43.421 | 56.433 | 1.00 | 53.59 | G | N |
| ATOM | 8324 | CA | SER | G | 519 | 8.485 | 42.056 | 55.948 | 1.00 | 53.59 | G | C |
| ATOM | 8325 | CB | SER | G | 519 | 8.196 | 41.978 | 54.445 | 1.00 | 52.96 | G | C |
| ATOM | 8326 | OG | SER | G | 519 | 8.702 | 40.769 | 53.907 | 1.00 | 52.43 | G | O |
| ATOM | 8327 | C | SER | G | 519 | 9.922 | 41.650 | 56.232 | 1.00 | 53.26 | G | C |
| ATOM | 8328 | O | SER | G | 519 | 10.184 | 40.677 | 56.953 | 1.00 | 50.56 | G | O |
| ATOM | 8329 | N | GLY | G | 520 | 10.840 | 42.436 | 55.671 | 1.00 | 53.16 | G | N |
| ATOM | 8330 | CA | GLY | G | 520 | 12.260 | 42.194 | 55.834 | 1.00 | 52.29 | G | C |
| ATOM | 8331 | C | GLY | G | 520 | 12.827 | 41.209 | 54.825 | 1.00 | 52.44 | G | C |
| ATOM | 8332 | O | GLY | G | 520 | 13.995 | 41.314 | 54.448 | 1.00 | 54.53 | G | O |
| ATOM | 8333 | N | HIS | G | 521 | 11.996 | 40.268 | 54.378 | 1.00 | 50.95 | G | N |
| ATOM | 8334 | CA | HIS | G | 521 | 12.402 | 39.226 | 53.432 | 1.00 | 50.20 | G | C |
| ATOM | 8335 | CB | HIS | G | 521 | 12.221 | 37.868 | 54.105 | 1.00 | 53.10 | G | C |
| ATOM | 8336 | CG | HIS | G | 521 | 10.965 | 37.772 | 54.923 | 1.00 | 56.56 | G | C |
| ATOM | 8337 | CD2 | HIS | G | 521 | 9.678 | 38.079 | 54.624 | 1.00 | 57.32 | G | C |
| ATOM | 8338 | ND1 | HIS | G | 521 | 10.957 | 37.342 | 56.234 | 1.00 | 58.92 | G | N |
| ATOM | 8339 | CE1 | HIS | G | 521 | 9.723 | 37.390 | 56.706 | 1.00 | 58.76 | G | C |
| ATOM | 8340 | NE2 | HIS | G | 521 | 8.928 | 37.834 | 55.749 | 1.00 | 59.02 | G | N |
| ATOM | 8341 | C | HIS | G | 521 | 11.579 | 39.250 | 52.135 | 1.00 | 48.14 | G | C |
| ATOM | 8342 | O | HIS | G | 521 | 10.512 | 38.633 | 52.063 | 1.00 | 49.91 | G | O |
| ATOM | 8343 | N | MET | G | 522 | 12.054 | 39.931 | 51.100 | 1.00 | 44.93 | G | N |
| ATOM | 8344 | CA | MET | G | 522 | 11.257 | 39.952 | 49.882 | 1.00 | 45.74 | G | C |
| ATOM | 8345 | CB | MET | G | 522 | 11.532 | 41.186 | 49.036 | 1.00 | 46.82 | G | C |
| ATOM | 8346 | CG | MET | G | 522 | 10.355 | 41.442 | 48.111 | 1.00 | 49.52 | G | C |
| ATOM | 8347 | SD | MET | G | 522 | 10.712 | 42.407 | 46.671 | 1.00 | 53.61 | G | S |
| ATOM | 8348 | CE | MET | G | 522 | 11.249 | 43.972 | 47.437 | 1.00 | 54.37 | G | C |
| ATOM | 8349 | C | MET | G | 522 | 11.372 | 38.734 | 48.983 | 1.00 | 42.34 | G | C |
| ATOM | 8350 | O | MET | G | 522 | 12.397 | 38.049 | 48.957 | 1.00 | 42.03 | G | O |
| ATOM | 8351 | N | PHE | G | 523 | 10.291 | 38.485 | 48.247 | 1.00 | 38.13 | G | N |
| ATOM | 8352 | CA | PHE | G | 523 | 10.199 | 37.372 | 47.309 | 1.00 | 34.33 | G | C |
| ATOM | 8353 | CB | PHE | G | 523 | 8.942 | 37.541 | 46.450 | 1.00 | 30.96 | G | C |
| ATOM | 8354 | CG | PHE | G | 523 | 8.615 | 36.344 | 45.610 | 1.00 | 28.77 | G | C |
| ATOM | 8355 | CD1 | PHE | G | 523 | 8.605 | 35.066 | 46.161 | 1.00 | 26.77 | G | C |
| ATOM | 8356 | CD2 | PHE | G | 523 | 8.288 | 36.496 | 44.268 | 1.00 | 26.27 | G | C |
| ATOM | 8357 | CE1 | PHE | G | 523 | 8.270 | 33.963 | 45.384 | 1.00 | 27.81 | G | C |
| ATOM | 8358 | CE2 | PHE | G | 523 | 7.952 | 35.400 | 43.486 | 1.00 | 25.34 | G | C |
| ATOM | 8359 | CZ | PHE | G | 523 | 7.942 | 34.130 | 44.045 | 1.00 | 24.97 | G | C |
| ATOM | 8360 | C | PHE | G | 523 | 11.431 | 37.260 | 46.402 | 1.00 | 33.05 | G | C |
| ATOM | 8361 | O | PHE | G | 523 | 11.871 | 38.238 | 45.795 | 1.00 | 31.24 | G | O |
| ATOM | 8362 | N | SER | G | 524 | 11.980 | 36.057 | 46.311 | 1.00 | 32.82 | G | N |
| ATOM | 8363 | CA | SER | G | 524 | 13.148 | 35.827 | 45.486 | 1.00 | 34.54 | G | C |
| ATOM | 8364 | CB | SER | G | 524 | 14.410 | 36.292 | 46.209 | 1.00 | 35.07 | G | C |
| ATOM | 8365 | OG | SER | G | 524 | 15.117 | 35.179 | 46.727 | 1.00 | 37.25 | G | O |
| ATOM | 8366 | C | SER | G | 524 | 13.290 | 34.356 | 45.124 | 1.00 | 37.11 | G | C |
| ATOM | 8367 | O | SER | G | 524 | 12.427 | 33.521 | 45.437 | 1.00 | 36.41 | G | O |
| ATOM | 8368 | N | SER | G | 525 | 14.393 | 34.052 | 44.455 | 1.00 | 38.43 | G | N |
| ATOM | 8369 | CA | SER | G | 525 | 14.675 | 32.693 | 44.031 | 1.00 | 41.25 | G | C |
| ATOM | 8370 | CB | SER | G | 525 | 15.828 | 32.703 | 43.034 | 1.00 | 41.52 | G | C |
| ATOM | 8371 | OG | SER | G | 525 | 15.448 | 32.011 | 41.865 | 1.00 | 45.71 | G | O |
| ATOM | 8372 | C | SER | G | 525 | 15.037 | 31.823 | 45.223 | 1.00 | 39.81 | G | C |
| ATOM | 8373 | O | SER | G | 525 | 14.830 | 30.610 | 45.206 | 1.00 | 38.76 | G | O |
| ATOM | 8374 | N | LYS | G | 526 | 15.581 | 32.463 | 46.252 | 1.00 | 39.74 | G | N |
| ATOM | 8375 | CA | LYS | G | 526 | 15.993 | 31.780 | 47.473 | 1.00 | 41.03 | G | C |
| ATOM | 8376 | CB | LYS | G | 526 | 17.001 | 32.645 | 48.243 | 1.00 | 43.98 | G | C |
| ATOM | 8377 | CG | LYS | G | 526 | 17.920 | 33.483 | 47.369 | 1.00 | 46.92 | G | C |
| ATOM | 8378 | CD | LYS | G | 526 | 19.139 | 32.682 | 46.930 | 1.00 | 51.16 | G | C |
| ATOM | 8379 | CE | LYS | G | 526 | 20.383 | 33.564 | 46.844 | 1.00 | 54.17 | G | C |
| ATOM | 8380 | NZ | LYS | G | 526 | 21.552 | 32.965 | 47.560 | 1.00 | 55.82 | G | N |
| ATOM | 8381 | C | LYS | G | 526 | 14.796 | 31.474 | 48.375 | 1.00 | 39.28 | G | C |
| ATOM | 8382 | O | LYS | G | 526 | 14.817 | 30.520 | 49.157 | 1.00 | 38.43 | G | O |
| ATOM | 8383 | N | SER | G | 527 | 13.753 | 32.289 | 48.258 | 1.00 | 37.01 | G | N |
| ATOM | 8384 | CA | SER | G | 527 | 12.557 | 32.119 | 49.068 | 1.00 | 34.33 | G | C |
| ATOM | 8385 | CB | SER | G | 527 | 11.455 | 33.067 | 48.590 | 1.00 | 31.47 | G | C |
| ATOM | 8386 | OG | SER | G | 527 | 11.697 | 34.385 | 49.040 | 1.00 | 34.73 | G | O |
| ATOM | 8387 | C | SER | G | 527 | 12.024 | 30.690 | 49.072 | 1.00 | 33.60 | G | C |
| ATOM | 8388 | O | SER | G | 527 | 11.828 | 30.084 | 48.020 | 1.00 | 35.95 | G | O |
| ATOM | 8389 | N | PRO | G | 528 | 11.817 | 30.119 | 50.270 | 1.00 | 32.65 | G | N |
| ATOM | 8390 | CD | PRO | G | 528 | 12.117 | 30.673 | 51.605 | 1.00 | 29.44 | G | C |
| ATOM | 8391 | CA | PRO | G | 528 | 11.291 | 28.752 | 50.341 | 1.00 | 30.33 | G | C |
| ATOM | 8392 | CB | PRO | G | 528 | 11.248 | 28.451 | 51.842 | 1.00 | 28.91 | G | C |
| ATOM | 8393 | CG | PRO | G | 528 | 11.355 | 29.779 | 52.519 | 1.00 | 29.85 | G | C |
| ATOM | 8394 | C | PRO | G | 528 | 9.905 | 28.660 | 49.713 | 1.00 | 28.93 | G | C |
| ATOM | 8395 | O | PRO | G | 528 | 9.166 | 29.645 | 49.688 | 1.00 | 30.12 | G | O |
| ATOM | 8396 | N | LYS | G | 529 | 9.562 | 27.486 | 49.192 | 1.00 | 28.01 | G | N |
| ATOM | 8397 | CA | LYS | G | 529 | 8.245 | 27.277 | 48.603 | 1.00 | 29.02 | G | C |
| ATOM | 8398 | CB | LYS | G | 529 | 8.177 | 25.932 | 47.880 | 1.00 | 30.09 | G | C |
| ATOM | 8399 | CG | LYS | G | 529 | 9.345 | 25.671 | 46.947 | 1.00 | 29.43 | G | C |
| ATOM | 8400 | CD | LYS | G | 529 | 9.078 | 26.231 | 45.559 | 1.00 | 31.63 | G | C |
| ATOM | 8401 | CE | LYS | G | 529 | 10.030 | 27.380 | 45.231 | 1.00 | 31.90 | G | C |
| ATOM | 8402 | NZ | LYS | G | 529 | 11.147 | 26.985 | 44.327 | 1.00 | 30.74 | G | N |
| ATOM | 8403 | C | LYS | G | 529 | 7.284 | 27.285 | 49.783 | 1.00 | 29.29 | G | C |
| ATOM | 8404 | O | LYS | G | 529 | 7.714 | 27.149 | 50.935 | 1.00 | 30.58 | G | O |
| ATOM | 8405 | N | PRO | G | 530 | 5.975 | 27.473 | 49.523 | 1.00 | 30.10 | G | N |
| ATOM | 8406 | CD | PRO | G | 530 | 5.373 | 27.718 | 48.200 | 1.00 | 28.13 | G | C |
| ATOM | 8407 | CA | PRO | G | 530 | 4.955 | 27.508 | 50.585 | 1.00 | 27.87 | G | C |
| ATOM | 8408 | CB | PRO | G | 530 | 3.637 | 27.589 | 49.811 | 1.00 | 22.64 | G | C |
| ATOM | 8409 | CG | PRO | G | 530 | 4.007 | 28.281 | 48.562 | 1.00 | 25.14 | G | C |
| ATOM | 8410 | C | PRO | G | 530 | 4.973 | 26.351 | 51.588 | 1.00 | 28.59 | G | C |
| ATOM | 8411 | O | PRO | G | 530 | 4.921 | 26.563 | 52.802 | 1.00 | 28.07 | G | O |
| ATOM | 8412 | N | GLN | G | 531 | 5.036 | 25.126 | 51.083 | 1.00 | 29.37 | G | N |
| ATOM | 8413 | CA | GLN | G | 531 | 5.048 | 23.970 | 51.963 | 1.00 | 31.18 | G | C |
| ATOM | 8414 | CB | GLN | G | 531 | 4.907 | 22.675 | 51.150 | 1.00 | 31.94 | G | C |
| ATOM | 8415 | CG | GLN | G | 531 | 6.125 | 22.305 | 50.309 | 1.00 | 36.58 | G | C |
| ATOM | 8416 | CD | GLN | G | 531 | 6.135 | 22.962 | 48.933 | 1.00 | 38.65 | G | C |
| ATOM | 8417 | OE1 | GLN | G | 531 | 5.319 | 23.853 | 48.635 | 1.00 | 36.56 | G | O |
| ATOM | 8418 | NE2 | GLN | G | 531 | 7.068 | 22.528 | 48.085 | 1.00 | 37.82 | G | N |
| ATOM | 8419 | C | GLN | G | 531 | 6.320 | 23.943 | 52.797 | 1.00 | 29.94 | G | C |
| ATOM | 8420 | O | GLN | G | 531 | 6.363 | 23.281 | 53.822 | 1.00 | 31.40 | G | O |
| ATOM | 8421 | N | GLU | G | 532 | 7.343 | 24.670 | 52.355 | 1.00 | 30.86 | G | N |
| ATOM | 8422 | CA | GLU | G | 532 | 8.612 | 24.744 | 53.071 | 1.00 | 30.39 | G | C |
| ATOM | 8423 | CB | GLU | G | 532 | 9.776 | 24.904 | 52.091 | 1.00 | 34.29 | G | C |
| ATOM | 8424 | CG | GLU | G | 532 | 10.063 | 23.697 | 51.220 | 1.00 | 40.71 | G | C |
| ATOM | 8425 | CD | GLU | G | 532 | 10.867 | 24.054 | 49.960 | 1.00 | 47.94 | G | C |
| ATOM | 8426 | OE1 | GLU | G | 532 | 11.557 | 25.111 | 49.933 | 1.00 | 47.85 | G | O |
| ATOM | 8427 | OE2 | GLU | G | 532 | 10.808 | 23.262 | 48.990 | 1.00 | 50.80 | G | O |
| ATOM | 8428 | C | GLU | G | 532 | 8.628 | 25.925 | 54.039 | 1.00 | 30.38 | G | C |
| ATOM | 8429 | O | GLU | G | 532 | 9.524 | 26.030 | 54.865 | 1.00 | 33.69 | G | O |
| ATOM | 8430 | N | TRP | G | 533 | 7.654 | 26.825 | 53.924 | 1.00 | 30.16 | G | N |
| ATOM | 8431 | CA | TRP | G | 533 | 7.579 | 27.987 | 54.810 | 1.00 | 27.05 | G | C |
| ATOM | 8432 | CB | TRP | G | 533 | 6.807 | 29.131 | 54.141 | 1.00 | 23.78 | G | C |
| ATOM | 8433 | CG | TRP | G | 533 | 6.953 | 30.446 | 54.857 | 1.00 | 24.29 | G | C |
| ATOM | 8434 | CD2 | TRP | G | 533 | 7.741 | 31.580 | 54.438 | 1.00 | 24.15 | G | C |
| ATOM | 8435 | CE2 | TRP | G | 533 | 7.603 | 32.574 | 55.437 | 1.00 | 21.45 | G | C |
| ATOM | 8436 | CE3 | TRP | G | 533 | 8.550 | 31.848 | 53.318 | 1.00 | 21.62 | G | C |
| ATOM | 8437 | CD1 | TRP | G | 533 | 6.388 | 30.796 | 56.051 | 1.00 | 21.17 | G | C |
| ATOM | 8438 | NE1 | TRP | G | 533 | 6.775 | 32.068 | 56.405 | 1.00 | 21.53 | G | N |
| ATOM | 8439 | CZ2 | TRP | G | 533 | 8.241 | 33.819 | 55.353 | 1.00 | 23.46 | G | C |
| ATOM | 8440 | CZ3 | TRP | G | 533 | 9.190 | 33.095 | 53.233 | 1.00 | 19.65 | G | C |
| ATOM | 8441 | CH2 | TRP | G | 533 | 9.029 | 34.060 | 54.245 | 1.00 | 23.92 | G | C |
| ATOM | 8442 | C | TRP | G | 533 | 6.875 | 27.553 | 56.087 | 1.00 | 26.75 | G | C |
| ATOM | 8443 | O | TRP | G | 533 | 5.657 | 27.652 | 56.210 | 1.00 | 25.89 | G | O |
| ATOM | 8444 | N | THR | G | 534 | 7.660 | 27.069 | 57.042 | 1.00 | 27.83 | G | N |
| ATOM | 8445 | CA | THR | G | 534 | 7.120 | 26.590 | 58.309 | 1.00 | 29.32 | G | C |
| ATOM | 8446 | CB | THR | G | 534 | 7.743 | 25.255 | 58.676 | 1.00 | 30.72 | G | C |
| ATOM | 8447 | OG1 | THR | G | 534 | 9.168 | 25.382 | 58.601 | 1.00 | 31.42 | G | O |
| ATOM | 8448 | CG2 | THR | G | 534 | 7.280 | 24.157 | 57.713 | 1.00 | 29.76 | G | C |
| ATOM | 8449 | C | THR | G | 534 | 7.357 | 27.540 | 59.478 | 1.00 | 29.54 | G | C |
| ATOM | 8450 | O | THR | G | 534 | 6.752 | 27.374 | 60.536 | 1.00 | 29.20 | G | O |
| ATOM | 8451 | N | LEU | G | 535 | 8.235 | 28.524 | 59.298 | 1.00 | 29.32 | G | N |
| ATOM | 8452 | CA | LEU | G | 535 | 8.516 | 29.476 | 60.364 | 1.00 | 28.79 | G | C |
| ATOM | 8453 | CB | LEU | G | 535 | 9.684 | 30.380 | 59.982 | 1.00 | 28.71 | G | C |
| ATOM | 8454 | CG | LEU | G | 535 | 9.440 | 31.322 | 58.806 | 1.00 | 32.83 | G | C |
| ATOM | 8455 | CD1 | LEU | G | 535 | 10.397 | 32.487 | 58.881 | 1.00 | 31.83 | G | C |
| ATOM | 8456 | CD2 | LEU | G | 535 | 9.633 | 30.565 | 57.500 | 1.00 | 38.07 | G | C |
| ATOM | 8457 | C | LEU | G | 535 | 7.281 | 30.314 | 60.677 | 1.00 | 31.75 | G | C |
| ATOM | 8458 | O | LEU | G | 535 | 6.279 | 30.264 | 59.953 | 1.00 | 35.18 | G | O |
| ATOM | 8459 | N | GLU | G | 536 | 7.353 | 31.091 | 61.751 | 1.00 | 30.49 | G | N |
| ATOM | 8460 | CA | GLU | G | 536 | 6.221 | 31.897 | 62.164 | 1.00 | 33.25 | G | C |
| ATOM | 8461 | CB | GLU | G | 536 | 6.321 | 32.206 | 63.658 | 1.00 | 36.75 | G | C |
| ATOM | 8462 | CG | GLU | G | 536 | 5.050 | 31.911 | 64.427 | 1.00 | 42.95 | G | C |
| ATOM | 8463 | CD | GLU | G | 536 | 5.290 | 31.805 | 65.919 | 1.00 | 46.73 | G | C |
| ATOM | 8464 | OE1 | GLU | G | 536 | 5.013 | 32.791 | 66.646 | 1.00 | 48.44 | G | O |
| ATOM | 8465 | OE2 | GLU | G | 536 | 5.757 | 30.732 | 66.358 | 1.00 | 46.82 | G | O |
| ATOM | 8466 | C | GLU | G | 536 | 6.090 | 33.194 | 61.393 | 1.00 | 31.89 | G | C |
| ATOM | 8467 | O | GLU | G | 536 | 5.001 | 33.768 | 61.331 | 1.00 | 32.19 | G | O |
| ATOM | 8468 | N | LYS | G | 537 | 7.198 | 33.650 | 60.816 | 1.00 | 30.39 | G | N |
| ATOM | 8469 | CA | LYS | G | 537 | 7.230 | 34.898 | 60.059 | 1.00 | 30.99 | G | C |
| ATOM | 8470 | CB | LYS | G | 537 | 8.631 | 35.145 | 59.499 | 1.00 | 32.74 | G | C |
| ATOM | 8471 | CG | LYS | G | 537 | 9.484 | 36.067 | 60.347 | 1.00 | 40.26 | G | C |
| ATOM | 8472 | CD | LYS | G | 537 | 9.196 | 37.536 | 60.054 | 1.00 | 45.70 | G | C |
| ATOM | 8473 | CE | LYS | G | 537 | 10.088 | 38.453 | 60.893 | 1.00 | 49.75 | G | C |
| ATOM | 8474 | NZ | LYS | G | 537 | 9.312 | 39.551 | 61.565 | 1.00 | 52.95 | G | N |
| ATOM | 8475 | C | LYS | G | 537 | 6.227 | 34.909 | 58.910 | 1.00 | 29.92 | G | C |
| ATOM | 8476 | O | LYS | G | 537 | 6.023 | 33.906 | 58.227 | 1.00 | 29.12 | G | O |
| ATOM | 8477 | N | ASN | G | 538 | 5.607 | 36.061 | 58.703 | 1.00 | 27.15 | G | N |
| ATOM | 8478 | CA | ASN | G | 538 | 4.625 | 36.220 | 57.644 | 1.00 | 23.35 | G | C |
| ATOM | 8479 | CB | ASN | G | 538 | 3.733 | 37.428 | 57.940 | 1.00 | 21.45 | G | C |
| ATOM | 8480 | CG | ASN | G | 538 | 2.359 | 37.310 | 57.313 | 1.00 | 19.82 | G | C |
| ATOM | 8481 | OD1 | ASN | G | 538 | 1.882 | 36.209 | 57.061 | 1.00 | 20.55 | G | O |
| ATOM | 8482 | ND2 | ASN | G | 538 | 1.714 | 38.451 | 57.062 | 1.00 | 18.08 | G | N |
| ATOM | 8483 | C | ASN | G | 538 | 5.348 | 36.467 | 56.338 | 1.00 | 22.53 | G | C |
| ATOM | 8484 | O | ASN | G | 538 | 6.237 | 37.312 | 56.279 | 1.00 | 22.65 | G | O |
| ATOM | 8485 | N | PRO | G | 539 | 5.014 | 35.703 | 55.282 | 1.00 | 21.19 | G | N |
| ATOM | 8486 | CD | PRO | G | 539 | 4.068 | 34.575 | 55.220 | 1.00 | 18.26 | G | C |
| ATOM | 8487 | CA | PRO | G | 539 | 5.688 | 35.941 | 53.994 | 1.00 | 20.75 | G | C |
| ATOM | 8488 | CB | PRO | G | 539 | 5.013 | 34.951 | 53.041 | 1.00 | 19.22 | G | C |
| ATOM | 8489 | CG | PRO | G | 539 | 4.433 | 33.889 | 53.929 | 1.00 | 18.63 | G | C |
| ATOM | 8490 | C | PRO | G | 539 | 5.438 | 37.403 | 53.564 | 1.00 | 20.08 | G | C |
| ATOM | 8491 | O | PRO | G | 539 | 4.453 | 38.011 | 53.971 | 1.00 | 20.32 | G | O |
| ATOM | 8492 | N | SER | G | 540 | 6.330 | 37.964 | 52.754 | 1.00 | 20.86 | G | N |
| ATOM | 8493 | CA | SER | G | 540 | 6.187 | 39.341 | 52.283 | 1.00 | 18.58 | G | C |
| ATOM | 8494 | CB | SER | G | 540 | 7.428 | 39.747 | 51.485 | 1.00 | 19.50 | G | C |
| ATOM | 8495 | OG | SER | G | 540 | 7.495 | 39.038 | 50.258 | 1.00 | 21.96 | G | O |
| ATOM | 8496 | C | SER | G | 540 | 4.937 | 39.531 | 51.412 | 1.00 | 20.27 | G | C |
| ATOM | 8497 | O | SER | G | 540 | 4.281 | 38.560 | 51.003 | 1.00 | 19.20 | G | O |
| ATOM | 8498 | N | TYR | G | 541 | 4.617 | 40.795 | 51.142 | 1.00 | 19.48 | G | N |
| ATOM | 8499 | CA | TYR | G | 541 | 3.472 | 41.163 | 50.318 | 1.00 | 16.07 | G | C |
| ATOM | 8500 | CB | TYR | G | 541 | 3.413 | 42.691 | 50.225 | 1.00 | 16.28 | G | C |
| ATOM | 8501 | CG | TYR | G | 541 | 2.300 | 43.257 | 49.376 | 1.00 | 19.80 | G | C |
| ATOM | 8502 | CD1 | TYR | G | 541 | 2.428 | 43.352 | 47.987 | 1.00 | 19.23 | G | C |
| ATOM | 8503 | CE1 | TYR | G | 541 | 1.395 | 43.892 | 47.212 | 1.00 | 17.97 | G | C |
| ATOM | 8504 | CD2 | TYR | G | 541 | 1.117 | 43.716 | 49.963 | 1.00 | 18.61 | G | C |
| ATOM | 8505 | CE2 | TYR | G | 541 | 0.090 | 44.252 | 49.200 | 1.00 | 17.83 | G | C |
| ATOM | 8506 | CZ | TYR | G | 541 | 0.230 | 44.337 | 47.828 | 1.00 | 18.58 | G | C |
| ATOM | 8507 | OH | TYR | G | 541 | −0.822 | 44.833 | 47.085 | 1.00 | 16.67 | G | O |
| ATOM | 8508 | C | TYR | G | 541 | 3.598 | 40.531 | 48.922 | 1.00 | 15.94 | G | C |
| ATOM | 8509 | O | TYR | G | 541 | 2.659 | 39.927 | 48.416 | 1.00 | 16.71 | G | O |
| ATOM | 8510 | N | THR | G | 542 | 4.767 | 40.653 | 48.306 | 1.00 | 17.15 | G | N |
| ATOM | 8511 | CA | THR | G | 542 | 4.978 | 40.088 | 46.975 | 1.00 | 19.52 | G | C |
| ATOM | 8512 | CB | THR | G | 542 | 6.345 | 40.510 | 46.421 | 1.00 | 18.14 | G | C |
| ATOM | 8513 | OG1 | THR | G | 542 | 6.361 | 41.934 | 46.283 | 1.00 | 14.96 | G | O |
| ATOM | 8514 | CG2 | THR | G | 542 | 6.595 | 39.872 | 45.063 | 1.00 | 17.34 | G | C |
| ATOM | 8515 | C | THR | G | 542 | 4.850 | 38.564 | 46.971 | 1.00 | 20.29 | G | C |
| ATOM | 8516 | O | THR | G | 542 | 4.297 | 37.983 | 46.031 | 1.00 | 21.53 | G | O |
| ATOM | 8517 | N | TYR | G | 543 | 5.345 | 37.924 | 48.027 | 1.00 | 21.04 | G | N |
| ATOM | 8518 | CA | TYR | G | 543 | 5.248 | 36.467 | 48.157 | 1.00 | 19.45 | G | C |
| ATOM | 8519 | CB | TYR | G | 543 | 5.857 | 36.025 | 49.487 | 1.00 | 19.32 | G | C |
| ATOM | 8520 | CG | TYR | G | 543 | 6.046 | 34.530 | 49.632 | 1.00 | 18.15 | G | C |
| ATOM | 8521 | CD1 | TYR | G | 543 | 4.974 | 33.699 | 49.962 | 1.00 | 18.56 | G | C |
| ATOM | 8522 | CE1 | TYR | G | 543 | 5.150 | 32.324 | 50.133 | 1.00 | 18.16 | G | C |
| ATOM | 8523 | CD2 | TYR | G | 543 | 7.303 | 33.949 | 49.475 | 1.00 | 18.13 | G | C |
| ATOM | 8524 | CE2 | TYR | G | 543 | 7.492 | 32.574 | 49.643 | 1.00 | 18.41 | G | C |
| ATOM | 8525 | CZ | TYR | G | 543 | 6.409 | 31.773 | 49.972 | 1.00 | 19.29 | G | C |
| ATOM | 8526 | OH | TYR | G | 543 | 6.575 | 30.420 | 50.135 | 1.00 | 20.94 | G | O |
| ATOM | 8527 | C | TYR | G | 543 | 3.768 | 36.073 | 48.113 | 1.00 | 18.98 | G | C |
| ATOM | 8528 | O | TYR | G | 543 | 3.372 | 35.128 | 47.415 | 1.00 | 17.77 | G | O |
| ATOM | 8529 | N | TYR | G | 544 | 2.954 | 36.793 | 48.876 | 1.00 | 17.72 | G | N |
| ATOM | 8530 | CA | TYR | G | 544 | 1.524 | 36.531 | 48.905 | 1.00 | 18.35 | G | C |
| ATOM | 8531 | CB | TYR | G | 544 | 0.836 | 37.455 | 49.923 | 1.00 | 19.21 | G | C |
| ATOM | 8532 | CG | TYR | G | 544 | 0.687 | 36.926 | 51.342 | 1.00 | 19.00 | G | C |
| ATOM | 8533 | CD1 | TYR | G | 544 | 1.652 | 37.207 | 52.321 | 1.00 | 18.53 | G | C |
| ATOM | 8534 | CE1 | TYR | G | 544 | 1.466 | 36.823 | 53.651 | 1.00 | 18.01 | G | C |
| ATOM | 8535 | CD2 | TYR | G | 544 | −0.466 | 36.232 | 51.734 | 1.00 | 17.55 | G | C |
| ATOM | 8536 | CE2 | TYR | G | 544 | −0.659 | 35.840 | 53.071 | 1.00 | 18.30 | G | C |
| ATOM | 8537 | CZ | TYR | G | 544 | 0.311 | 36.146 | 54.021 | 1.00 | 20.08 | G | C |
| ATOM | 8538 | OH | TYR | G | 544 | 0.114 | 35.799 | 55.348 | 1.00 | 23.59 | G | O |
| ATOM | 8539 | C | TYR | G | 544 | 0.934 | 36.801 | 47.494 | 1.00 | 21.34 | G | C |
| ATOM | 8540 | O | TYR | G | 544 | 0.192 | 35.977 | 46.940 | 1.00 | 20.30 | G | O |
| ATOM | 8541 | N | ALA | G | 545 | 1.271 | 37.955 | 46.919 | 1.00 | 19.22 | G | N |
| ATOM | 8542 | CA | ALA | G | 545 | 0.757 | 38.339 | 45.607 | 1.00 | 17.69 | G | C |
| ATOM | 8543 | CB | ALA | G | 545 | 1.306 | 39.717 | 45.208 | 1.00 | 14.50 | G | C |
| ATOM | 8544 | C | ALA | G | 545 | 1.103 | 37.307 | 44.538 | 1.00 | 18.43 | G | C |
| ATOM | 8545 | O | ALA | G | 545 | 0.244 | 36.922 | 43.742 | 1.00 | 18.04 | G | O |
| ATOM | 8546 | N | TYR | G | 546 | 2.350 | 36.849 | 44.510 | 1.00 | 15.93 | G | N |
| ATOM | 8547 | CA | TYR | G | 546 | 2.710 | 35.887 | 43.493 | 1.00 | 18.47 | G | C |
| ATOM | 8548 | CB | TYR | G | 546 | 4.182 | 35.480 | 43.586 | 1.00 | 19.77 | G | C |
| ATOM | 8549 | CG | TYR | G | 546 | 4.492 | 34.391 | 42.584 | 1.00 | 22.57 | G | C |
| ATOM | 8550 | CD1 | TYR | G | 546 | 4.656 | 34.692 | 41.230 | 1.00 | 24.54 | G | C |
| ATOM | 8551 | CE1 | TYR | G | 546 | 4.824 | 33.687 | 40.279 | 1.00 | 23.62 | G | C |
| ATOM | 8552 | CD2 | TYR | G | 546 | 4.514 | 33.052 | 42.966 | 1.00 | 23.25 | G | C |
| ATOM | 8553 | CE2 | TYR | G | 546 | 4.680 | 32.038 | 42.027 | 1.00 | 26.24 | G | C |
| ATOM | 8554 | CZ | TYR | G | 546 | 4.832 | 32.361 | 40.680 | 1.00 | 28.90 | G | C |
| ATOM | 8555 | OH | TYR | G | 546 | 4.966 | 31.356 | 39.735 | 1.00 | 32.24 | G | O |
| ATOM | 8556 | C | TYR | G | 546 | 1.859 | 34.632 | 43.555 | 1.00 | 19.71 | G | C |
| ATOM | 8557 | O | TYR | G | 546 | 1.301 | 34.198 | 42.549 | 1.00 | 21.27 | G | O |
| ATOM | 8558 | N | TYR | G | 547 | 1.750 | 34.042 | 44.737 | 1.00 | 19.81 | G | N |
| ATOM | 8559 | CA | TYR | G | 547 | 0.993 | 32.811 | 44.861 | 1.00 | 17.54 | G | C |
| ATOM | 8560 | CB | TYR | G | 547 | 1.335 | 32.126 | 46.187 | 1.00 | 16.67 | G | C |
| ATOM | 8561 | CG | TYR | G | 547 | 2.704 | 31.484 | 46.120 | 1.00 | 16.74 | G | C |
| ATOM | 8562 | CD1 | TYR | G | 547 | 2.901 | 30.308 | 45.398 | 1.00 | 14.50 | G | C |
| ATOM | 8563 | CE1 | TYR | G | 547 | 4.178 | 29.765 | 45.239 | 1.00 | 15.25 | G | C |
| ATOM | 8564 | CD2 | TYR | G | 547 | 3.822 | 32.105 | 46.696 | 1.00 | 15.92 | G | C |
| ATOM | 8565 | CE2 | TYR | G | 547 | 5.106 | 31.568 | 46.542 | 1.00 | 13.48 | G | C |
| ATOM | 8566 | CZ | TYR | G | 547 | 5.274 | 30.399 | 45.809 | 1.00 | 17.57 | G | C |
| ATOM | 8567 | OH | TYR | G | 547 | 6.541 | 29.875 | 45.615 | 1.00 | 19.20 | G | O |
| ATOM | 8568 | C | TYR | G | 547 | −0.506 | 32.967 | 44.670 | 1.00 | 17.81 | G | C |
| ATOM | 8569 | O | TYR | G | 547 | −1.187 | 32.018 | 44.278 | 1.00 | 17.62 | G | O |
| ATOM | 8570 | N | MET | G | 548 | −1.035 | 34.154 | 44.929 | 1.00 | 15.58 | G | N |
| ATOM | 8571 | CA | MET | G | 548 | −2.456 | 34.347 | 44.720 | 1.00 | 16.26 | G | C |
| ATOM | 8572 | CB | MET | G | 548 | −2.927 | 35.596 | 45.457 | 1.00 | 16.29 | G | C |
| ATOM | 8573 | CG | MET | G | 548 | −3.346 | 35.285 | 46.888 | 1.00 | 18.61 | G | C |
| ATOM | 8574 | SD | MET | G | 548 | −4.447 | 36.515 | 47.580 | 1.00 | 29.71 | G | S |
| ATOM | 8575 | CE | MET | G | 548 | −6.039 | 35.832 | 47.144 | 1.00 | 25.28 | G | C |
| ATOM | 8576 | C | MET | G | 548 | −2.674 | 34.461 | 43.208 | 1.00 | 16.99 | G | C |
| ATOM | 8577 | O | MET | G | 548 | −3.616 | 33.879 | 42.650 | 1.00 | 15.21 | G | O |
| ATOM | 8578 | N | TYR | G | 549 | −1.776 | 35.189 | 42.550 | 1.00 | 15.86 | G | N |
| ATOM | 8579 | CA | TYR | G | 549 | −1.854 | 35.362 | 41.107 | 1.00 | 16.83 | G | C |
| ATOM | 8580 | CB | TYR | G | 549 | −0.738 | 36.300 | 40.615 | 1.00 | 15.45 | G | C |
| ATOM | 8581 | CG | TYR | G | 549 | −0.570 | 36.293 | 39.100 | 1.00 | 19.22 | G | C |
| ATOM | 8582 | CD1 | TYR | G | 549 | −1.337 | 37.135 | 38.284 | 1.00 | 17.58 | G | C |
| ATOM | 8583 | CE1 | TYR | G | 549 | −1.245 | 37.071 | 36.878 | 1.00 | 18.30 | G | C |
| ATOM | 8584 | CD2 | TYR | G | 549 | 0.305 | 35.392 | 38.474 | 1.00 | 19.26 | G | C |
| ATOM | 8585 | CE2 | TYR | G | 549 | 0.401 | 35.322 | 37.074 | 1.00 | 17.84 | G | C |
| ATOM | 8586 | CZ | TYR | G | 549 | −0.380 | 36.156 | 36.288 | 1.00 | 16.93 | G | C |
| ATOM | 8587 | OH | TYR | G | 549 | −0.348 | 36.041 | 34.921 | 1.00 | 18.12 | G | O |
| ATOM | 8588 | C | TYR | G | 549 | −1.708 | 33.993 | 40.433 | 1.00 | 18.13 | G | C |
| ATOM | 8589 | O | TYR | G | 549 | −2.499 | 33.620 | 39.565 | 1.00 | 18.71 | G | O |
| ATOM | 8590 | N | ALA | G | 550 | −0.688 | 33.248 | 40.848 | 1.00 | 18.51 | G | N |
| ATOM | 8591 | CA | ALA | G | 550 | −0.406 | 31.938 | 40.289 | 1.00 | 18.41 | G | C |
| ATOM | 8592 | CB | ALA | G | 550 | 0.774 | 31.301 | 41.030 | 1.00 | 18.08 | G | C |
| ATOM | 8593 | C | ALA | G | 550 | −1.610 | 30.999 | 40.316 | 1.00 | 20.80 | G | C |
| ATOM | 8594 | O | ALA | G | 550 | −1.919 | 30.349 | 39.312 | 1.00 | 21.58 | G | O |
| ATOM | 8595 | N | ASN | G | 551 | −2.290 | 30.922 | 41.459 | 1.00 | 19.37 | G | N |
| ATOM | 8596 | CA | ASN | G | 551 | −3.445 | 30.040 | 41.589 | 1.00 | 17.25 | G | C |
| ATOM | 8597 | CB | ASN | G | 551 | −3.790 | 29.835 | 43.069 | 1.00 | 18.22 | G | C |
| ATOM | 8598 | CG | ASN | G | 551 | −2.894 | 28.805 | 43.729 | 1.00 | 18.97 | G | C |
| ATOM | 8599 | OD1 | ASN | G | 551 | −1.898 | 29.147 | 44.371 | 1.00 | 20.35 | G | O |
| ATOM | 8600 | ND2 | ASN | G | 551 | −3.234 | 27.537 | 43.560 | 1.00 | 14.02 | G | N |
| ATOM | 8601 | C | ASN | G | 551 | −4.656 | 30.566 | 40.843 | 1.00 | 16.03 | G | C |
| ATOM | 8602 | O | ASN | G | 551 | −5.424 | 29.790 | 40.286 | 1.00 | 16.77 | G | O |
| ATOM | 8603 | N | ILE | G | 552 | −4.835 | 31.884 | 40.842 | 1.00 | 16.64 | G | N |
| ATOM | 8604 | CA | ILE | G | 552 | −5.962 | 32.492 | 40.141 | 1.00 | 15.74 | G | C |
| ATOM | 8605 | CB | ILE | G | 552 | −6.087 | 34.005 | 40.515 | 1.00 | 15.57 | G | C |
| ATOM | 8606 | CG2 | ILE | G | 552 | −7.020 | 34.746 | 39.532 | 1.00 | 11.36 | G | C |
| ATOM | 8607 | CG1 | ILE | G | 552 | −6.636 | 34.116 | 41.948 | 1.00 | 11.42 | G | C |
| ATOM | 8608 | CD1 | ILE | G | 552 | −6.602 | 35.511 | 42.528 | 1.00 | 7.43 | G | C |
| ATOM | 8609 | C | ILE | G | 552 | −5.780 | 32.294 | 38.625 | 1.00 | 16.13 | G | C |
| ATOM | 8610 | O | ILE | G | 552 | −6.743 | 32.082 | 37.896 | 1.00 | 15.46 | G | O |
| ATOM | 8611 | N | MET | G | 553 | −4.536 | 32.323 | 38.163 | 1.00 | 18.30 | G | N |
| ATOM | 8612 | CA | MET | G | 553 | −4.264 | 32.119 | 36.744 | 1.00 | 21.96 | G | C |
| ATOM | 8613 | CB | MET | G | 553 | −2.776 | 32.265 | 36.454 | 1.00 | 20.79 | G | C |
| ATOM | 8614 | CG | MET | G | 553 | −2.363 | 31.545 | 35.178 | 1.00 | 27.29 | G | C |
| ATOM | 8615 | SD | MET | G | 553 | −0.655 | 31.852 | 34.758 | 1.00 | 35.70 | G | S |
| ATOM | 8616 | CE | MET | G | 553 | −0.429 | 30.728 | 33.408 | 1.00 | 31.99 | G | C |
| ATOM | 8617 | C | MET | G | 553 | −4.717 | 30.724 | 36.298 | 1.00 | 22.80 | G | C |
| ATOM | 8618 | O | MET | G | 553 | −5.472 | 30.582 | 35.329 | 1.00 | 22.62 | G | O |
| ATOM | 8619 | N | VAL | G | 554 | −4.241 | 29.700 | 37.008 | 1.00 | 22.21 | G | N |
| ATOM | 8620 | CA | VAL | G | 554 | −4.590 | 28.315 | 36.692 | 1.00 | 18.89 | G | C |
| ATOM | 8621 | CB | VAL | G | 554 | −3.830 | 27.310 | 37.622 | 1.00 | 19.00 | G | C |
| ATOM | 8622 | CG1 | VAL | G | 554 | −4.159 | 25.873 | 37.233 | 1.00 | 17.63 | G | C |
| ATOM | 8623 | CG2 | VAL | G | 554 | −2.331 | 27.523 | 37.511 | 1.00 | 15.77 | G | C |
| ATOM | 8624 | C | VAL | G | 554 | −6.098 | 28.125 | 36.845 | 1.00 | 18.00 | G | C |
| ATOM | 8625 | O | VAL | G | 554 | −6.749 | 27.518 | 35.998 | 1.00 | 20.43 | G | O |
| ATOM | 8626 | N | LEU | G | 555 | −6.665 | 28.660 | 37.920 | 1.00 | 16.77 | G | N |
| ATOM | 8627 | CA | LEU | G | 555 | −8.095 | 28.527 | 38.148 | 1.00 | 14.16 | G | C |
| ATOM | 8628 | CB | LEU | G | 555 | −8.490 | 29.222 | 39.459 | 1.00 | 13.11 | G | C |
| ATOM | 8629 | CG | LEU | G | 555 | −9.974 | 29.180 | 39.864 | 1.00 | 11.09 | G | C |
| ATOM | 8630 | CD1 | LEU | G | 555 | −10.454 | 27.753 | 39.985 | 1.00 | 10.27 | G | C |
| ATOM | 8631 | CD2 | LEU | G | 555 | −10.146 | 29.898 | 41.183 | 1.00 | 10.90 | G | C |
| ATOM | 8632 | C | LEU | G | 555 | −8.894 | 29.120 | 36.995 | 1.00 | 15.49 | G | C |
| ATOM | 8633 | O | LEU | G | 555 | −9.843 | 28.519 | 36.526 | 1.00 | 16.18 | G | O |
| ATOM | 8634 | N | ASN | G | 556 | −8.505 | 30.308 | 36.543 | 1.00 | 18.24 | G | N |
| ATOM | 8635 | CA | ASN | G | 556 | −9.212 | 30.977 | 35.460 | 1.00 | 16.14 | G | C |
| ATOM | 8636 | CB | ASN | G | 556 | −8.661 | 32.397 | 35.274 | 1.00 | 16.63 | G | C |
| ATOM | 8637 | CG | ASN | G | 556 | −9.189 | 33.381 | 36.326 | 1.00 | 17.35 | G | C |
| ATOM | 8638 | OD1 | ASN | G | 556 | −10.130 | 33.089 | 37.064 | 1.00 | 16.34 | G | O |
| ATOM | 8639 | ND2 | ASN | G | 556 | −8.580 | 34.550 | 36.387 | 1.00 | 16.64 | G | N |
| ATOM | 8640 | C | ASN | G | 556 | −9.116 | 30.188 | 34.157 | 1.00 | 17.89 | G | C |
| ATOM | 8641 | O | ASN | G | 556 | −10.082 | 30.120 | 33.398 | 1.00 | 16.94 | G | O |
| ATOM | 8642 | N | SER | G | 557 | −7.949 | 29.598 | 33.909 | 1.00 | 20.27 | G | N |
| ATOM | 8643 | CA | SER | G | 557 | −7.704 | 28.796 | 32.711 | 1.00 | 21.39 | G | C |
| ATOM | 8644 | CB | SER | G | 557 | −6.280 | 28.244 | 32.718 | 1.00 | 20.56 | G | C |
| ATOM | 8645 | OG | SER | G | 557 | −5.338 | 29.297 | 32.780 | 1.00 | 29.20 | G | O |
| ATOM | 8646 | C | SER | G | 557 | −8.670 | 27.628 | 32.695 | 1.00 | 22.73 | G | C |
| ATOM | 8647 | O | SER | G | 557 | −9.308 | 27.332 | 31.682 | 1.00 | 22.50 | G | O |
| ATOM | 8648 | N | LEU | G | 558 | −8.771 | 26.962 | 33.837 | 1.00 | 22.95 | G | N |
| ATOM | 8649 | CA | LEU | G | 558 | −9.647 | 25.821 | 33.959 | 1.00 | 22.60 | G | C |
| ATOM | 8650 | CB | LEU | G | 558 | −9.434 | 25.151 | 35.310 | 1.00 | 23.60 | G | C |
| ATOM | 8651 | CG | LEU | G | 558 | −10.395 | 24.010 | 35.654 | 1.00 | 27.89 | G | C |
| ATOM | 8652 | CD1 | LEU | G | 558 | −10.193 | 22.856 | 34.678 | 1.00 | 26.21 | G | C |
| ATOM | 8653 | CD2 | LEU | G | 558 | −10.142 | 23.549 | 37.085 | 1.00 | 26.87 | G | C |
| ATOM | 8654 | C | LEU | G | 558 | −11.109 | 26.211 | 33.792 | 1.00 | 22.85 | G | C |
| ATOM | 8655 | O | LEU | G | 558 | −11.842 | 25.578 | 33.034 | 1.00 | 22.08 | G | O |
| ATOM | 8656 | N | ARG | G | 559 | −11.528 | 27.275 | 34.468 | 1.00 | 23.45 | G | N |
| ATOM | 8657 | CA | ARG | G | 559 | −12.919 | 27.708 | 34.406 | 1.00 | 20.98 | G | C |
| ATOM | 8658 | CB | ARG | G | 559 | −13.199 | 28.761 | 35.487 | 1.00 | 18.32 | G | C |
| ATOM | 8659 | CG | ARG | G | 559 | −13.440 | 28.148 | 36.890 | 1.00 | 18.89 | G | C |
| ATOM | 8660 | CD | ARG | G | 559 | −13.786 | 29.201 | 37.942 | 1.00 | 15.42 | G | C |
| ATOM | 8661 | NE | ARG | G | 559 | −15.216 | 29.516 | 37.974 | 1.00 | 15.56 | G | N |
| ATOM | 8662 | CZ | ARG | G | 559 | −16.137 | 28.791 | 38.610 | 1.00 | 12.83 | G | C |
| ATOM | 8663 | NH1 | ARG | G | 559 | −15.794 | 27.693 | 39.277 | 1.00 | 11.89 | G | N |
| ATOM | 8664 | NH2 | ARG | G | 559 | −17.404 | 29.173 | 38.598 | 1.00 | 10.37 | G | N |
| ATOM | 8665 | C | ARG | G | 559 | −13.328 | 28.230 | 33.042 | 1.00 | 22.78 | G | C |
| ATOM | 8666 | O | ARG | G | 559 | −14.480 | 28.046 | 32.627 | 1.00 | 23.60 | G | O |
| ATOM | 8667 | N | LYS | G | 560 | −12.396 | 28.893 | 32.358 | 1.00 | 26.24 | G | N |
| ATOM | 8668 | CA | LYS | G | 560 | −12.655 | 29.435 | 31.021 | 1.00 | 26.87 | G | C |
| ATOM | 8669 | CB | LYS | G | 560 | −11.394 | 30.130 | 30.477 | 1.00 | 26.24 | G | C |
| ATOM | 8670 | CG | LYS | G | 560 | −11.499 | 30.630 | 29.037 | 1.00 | 29.68 | G | C |
| ATOM | 8671 | CD | LYS | G | 560 | −12.202 | 31.990 | 28.949 | 1.00 | 35.36 | G | C |
| ATOM | 8672 | CE | LYS | G | 560 | −12.176 | 32.583 | 27.523 | 1.00 | 39.47 | G | C |
| ATOM | 8673 | NZ | LYS | G | 560 | −12.338 | 34.097 | 27.479 | 1.00 | 37.02 | G | N |
| ATOM | 8674 | C | LYS | G | 560 | −13.034 | 28.255 | 30.127 | 1.00 | 26.02 | G | C |
| ATOM | 8675 | O | LYS | G | 560 | −14.062 | 28.264 | 29.459 | 1.00 | 26.15 | G | O |
| ATOM | 8676 | N | GLU | G | 561 | −12.206 | 27.221 | 30.153 | 1.00 | 28.67 | G | N |
| ATOM | 8677 | CA | GLU | G | 561 | −12.437 | 26.034 | 29.350 | 1.00 | 30.99 | G | C |
| ATOM | 8678 | CB | GLU | G | 561 | −11.291 | 25.051 | 29.546 | 1.00 | 35.08 | G | C |
| ATOM | 8679 | CG | GLU | G | 561 | −10.201 | 25.177 | 28.500 | 1.00 | 47.87 | G | C |
| ATOM | 8680 | CD | GLU | G | 561 | −9.009 | 24.291 | 28.807 | 1.00 | 54.46 | G | C |
| ATOM | 8681 | OE1 | GLU | G | 561 | −9.225 | 23.118 | 29.207 | 1.00 | 56.67 | G | O |
| ATOM | 8682 | OE2 | GLU | G | 561 | −7.857 | 24.767 | 28.651 | 1.00 | 58.44 | G | O |
| ATOM | 8683 | C | GLU | G | 561 | −13.755 | 25.344 | 29.654 | 1.00 | 31.33 | G | C |
| ATOM | 8684 | O | GLU | G | 561 | −14.361 | 24.757 | 28.762 | 1.00 | 34.68 | G | O |
| ATOM | 8685 | N | ARG | G | 562 | −14.200 | 25.410 | 30.909 | 1.00 | 29.74 | G | N |
| ATOM | 8686 | CA | ARG | G | 562 | −15.462 | 24.781 | 31.323 | 1.00 | 23.91 | G | C |
| ATOM | 8687 | CB | ARG | G | 562 | −15.481 | 24.532 | 32.843 | 1.00 | 22.02 | G | C |
| ATOM | 8688 | CG | ARG | G | 562 | −14.447 | 23.517 | 33.332 | 1.00 | 23.36 | G | C |
| ATOM | 8689 | CD | ARG | G | 562 | −15.049 | 22.485 | 34.272 | 1.00 | 27.03 | G | C |
| ATOM | 8690 | NE | ARG | G | 562 | −16.014 | 21.602 | 33.616 | 1.00 | 26.30 | G | N |
| ATOM | 8691 | CZ | ARG | G | 562 | −16.814 | 20.744 | 34.247 | 1.00 | 26.85 | G | C |
| ATOM | 8692 | NH1 | ARG | G | 562 | −16.783 | 20.631 | 35.570 | 1.00 | 26.56 | G | N |
| ATOM | 8693 | NH2 | ARG | G | 562 | −17.660 | 19.999 | 33.551 | 1.00 | 26.22 | G | N |
| ATOM | 8694 | C | ARG | G | 562 | −16.643 | 25.646 | 30.951 | 1.00 | 21.31 | G | C |
| ATOM | 8695 | O | ARG | G | 562 | −17.781 | 25.237 | 31.091 | 1.00 | 21.11 | G | O |
| ATOM | 8696 | N | GLY | G | 563 | −16.375 | 26.852 | 30.474 | 1.00 | 22.40 | G | N |
| ATOM | 8697 | CA | GLY | G | 563 | −17.468 | 27.735 | 30.121 | 1.00 | 21.45 | G | C |
| ATOM | 8698 | C | GLY | G | 563 | −17.991 | 28.468 | 31.345 | 1.00 | 23.42 | G | C |
| ATOM | 8699 | O | GLY | G | 563 | −19.081 | 29.049 | 31.308 | 1.00 | 22.76 | G | O |
| ATOM | 8700 | N | MET | G | 564 | −17.210 | 28.454 | 32.427 | 1.00 | 24.36 | G | N |
| ATOM | 8701 | CA | MET | G | 564 | −17.597 | 29.117 | 33.674 | 1.00 | 22.46 | G | C |
| ATOM | 8702 | CB | MET | G | 564 | −17.145 | 28.268 | 34.861 | 1.00 | 23.53 | G | C |
| ATOM | 8703 | CG | MET | G | 564 | −17.870 | 26.940 | 35.004 | 1.00 | 23.92 | G | C |
| ATOM | 8704 | SD | MET | G | 564 | −17.010 | 25.849 | 36.173 | 1.00 | 24.44 | G | S |
| ATOM | 8705 | CE | MET | G | 564 | −18.309 | 24.710 | 36.598 | 1.00 | 23.69 | G | C |
| ATOM | 8706 | C | MET | G | 564 | −16.974 | 30.512 | 33.782 | 1.00 | 22.79 | G | C |
| ATOM | 8707 | O | MET | G | 564 | −16.102 | 30.882 | 32.988 | 1.00 | 22.40 | G | O |
| ATOM | 8708 | N | ASN | G | 565 | −17.423 | 31.283 | 34.772 | 1.00 | 21.38 | G | N |
| ATOM | 8709 | CA | ASN | G | 565 | −16.900 | 32.630 | 35.000 | 1.00 | 17.00 | G | C |
| ATOM | 8710 | CB | ASN | G | 565 | −17.824 | 33.409 | 35.957 | 1.00 | 18.27 | G | C |
| ATOM | 8711 | CG | ASN | G | 565 | −17.980 | 32.733 | 37.332 | 1.00 | 16.81 | G | C |
| ATOM | 8712 | OD1 | ASN | G | 565 | −18.407 | 31.579 | 37.433 | 1.00 | 18.35 | G | O |
| ATOM | 8713 | ND2 | ASN | G | 565 | −17.642 | 33.465 | 38.392 | 1.00 | 16.52 | G | N |
| ATOM | 8714 | C | ASN | G | 565 | −15.481 | 32.564 | 35.571 | 1.00 | 17.92 | G | C |
| ATOM | 8715 | O | ASN | G | 565 | −15.105 | 31.564 | 36.212 | 1.00 | 17.43 | G | O |
| ATOM | 8716 | N | THR | G | 566 | −14.694 | 33.614 | 35.324 | 1.00 | 15.33 | G | N |
| ATOM | 8717 | CA | THR | G | 566 | −13.324 | 33.680 | 35.809 | 1.00 | 13.44 | G | C |
| ATOM | 8718 | CB | THR | G | 566 | −12.336 | 33.915 | 34.647 | 1.00 | 17.64 | G | C |
| ATOM | 8719 | OG1 | THR | G | 566 | −12.641 | 35.158 | 33.995 | 1.00 | 17.26 | G | O |
| ATOM | 8720 | CG2 | THR | G | 566 | −12.432 | 32.768 | 33.640 | 1.00 | 16.32 | G | C |
| ATOM | 8721 | C | THR | G | 566 | −13.233 | 34.814 | 36.825 | 1.00 | 13.73 | G | C |
| ATOM | 8722 | O | THR | G | 566 | −14.201 | 35.554 | 37.001 | 1.00 | 13.77 | G | O |
| ATOM | 8723 | N | PHE | G | 567 | −12.081 | 34.961 | 37.476 | 1.00 | 12.73 | G | N |
| ATOM | 8724 | CA | PHE | G | 567 | −11.924 | 35.978 | 38.516 | 1.00 | 13.81 | G | C |
| ATOM | 8725 | CB | PHE | G | 567 | −11.696 | 35.307 | 39.877 | 1.00 | 11.83 | G | C |
| ATOM | 8726 | CG | PHE | G | 567 | −12.642 | 34.187 | 40.161 | 1.00 | 10.82 | G | C |
| ATOM | 8727 | CD1 | PHE | G | 567 | −13.961 | 34.450 | 40.489 | 1.00 | 10.18 | G | C |
| ATOM | 8728 | CD2 | PHE | G | 567 | −12.217 | 32.867 | 40.080 | 1.00 | 11.77 | G | C |
| ATOM | 8729 | CE1 | PHE | G | 567 | −14.854 | 33.412 | 40.737 | 1.00 | 13.14 | G | C |
| ATOM | 8730 | CE2 | PHE | G | 567 | −13.098 | 31.819 | 40.323 | 1.00 | 14.86 | G | C |
| ATOM | 8731 | CZ | PHE | G | 567 | −14.423 | 32.091 | 40.653 | 1.00 | 12.25 | G | C |
| ATOM | 8732 | C | PHE | G | 567 | −10.817 | 36.984 | 38.325 | 1.00 | 14.97 | G | C |
| ATOM | 8733 | O | PHE | G | 567 | −9.771 | 36.683 | 37.739 | 1.00 | 16.85 | G | O |
| ATOM | 8734 | N | LEU | G | 568 | −11.045 | 38.180 | 38.866 | 1.00 | 15.71 | G | N |
| ATOM | 8735 | CA | LEU | G | 568 | −10.056 | 39.246 | 38.806 | 1.00 | 14.79 | G | C |
| ATOM | 8736 | CB | LEU | G | 568 | −10.748 | 40.602 | 38.604 | 1.00 | 13.47 | G | C |
| ATOM | 8737 | CG | LEU | G | 568 | −11.520 | 40.840 | 37.296 | 1.00 | 10.99 | G | C |
| ATOM | 8738 | CD1 | LEU | G | 568 | −11.918 | 42.303 | 37.213 | 1.00 | 7.36 | G | C |
| ATOM | 8739 | CD2 | LEU | G | 568 | −10.646 | 40.461 | 36.102 | 1.00 | 9.11 | G | C |
| ATOM | 8740 | C | LEU | G | 568 | −9.277 | 39.268 | 40.121 | 1.00 | 15.85 | G | C |
| ATOM | 8741 | O | LEU | G | 568 | −9.786 | 38.826 | 41.163 | 1.00 | 15.77 | G | O |
| ATOM | 8742 | N | PHE | G | 569 | −8.038 | 39.749 | 40.065 | 1.00 | 14.24 | G | N |
| ATOM | 8743 | CA | PHE | G | 569 | −7.210 | 39.891 | 41.260 | 1.00 | 15.11 | G | C |
| ATOM | 8744 | CB | PHE | G | 569 | −5.798 | 39.306 | 41.039 | 1.00 | 16.24 | G | C |
| ATOM | 8745 | CG | PHE | G | 569 | −4.898 | 39.383 | 42.260 | 1.00 | 12.61 | G | C |
| ATOM | 8746 | CD1 | PHE | G | 569 | −5.402 | 39.122 | 43.534 | 1.00 | 10.48 | G | C |
| ATOM | 8747 | CD2 | PHE | G | 569 | −3.550 | 39.727 | 42.129 | 1.00 | 11.44 | G | C |
| ATOM | 8748 | CE1 | PHE | G | 569 | −4.576 | 39.204 | 44.664 | 1.00 | 11.14 | G | C |
| ATOM | 8749 | CE2 | PHE | G | 569 | −2.707 | 39.814 | 43.259 | 1.00 | 12.66 | G | C |
| ATOM | 8750 | CZ | PHE | G | 569 | −3.225 | 39.552 | 44.526 | 1.00 | 11.06 | G | C |
| ATOM | 8751 | C | PHE | G | 569 | −7.134 | 41.407 | 41.489 | 1.00 | 14.19 | G | C |
| ATOM | 8752 | O | PHE | G | 569 | −6.530 | 42.128 | 40.685 | 1.00 | 12.41 | G | O |
| ATOM | 8753 | N | ARG | G | 570 | −7.775 | 41.877 | 42.565 | 1.00 | 14.41 | G | N |
| ATOM | 8754 | CA | ARG | G | 570 | −7.819 | 43.305 | 42.913 | 1.00 | 11.49 | G | C |
| ATOM | 8755 | CB | ARG | G | 570 | −9.216 | 43.841 | 42.640 | 1.00 | 10.21 | G | C |
| ATOM | 8756 | CG | ARG | G | 570 | −9.804 | 43.342 | 41.315 | 1.00 | 9.54 | G | C |
| ATOM | 8757 | CD | ARG | G | 570 | −11.308 | 43.585 | 41.208 | 1.00 | 8.99 | G | C |
| ATOM | 8758 | NE | ARG | G | 570 | −11.660 | 44.950 | 41.581 | 1.00 | 12.73 | G | N |
| ATOM | 8759 | CZ | ARG | G | 570 | −12.892 | 45.437 | 41.606 | 1.00 | 8.65 | G | C |
| ATOM | 8760 | NH1 | ARG | G | 570 | −13.923 | 44.673 | 41.274 | 1.00 | 8.36 | G | N |
| ATOM | 8761 | NH2 | ARG | G | 570 | −13.088 | 46.685 | 42.003 | 1.00 | 9.78 | G | N |
| ATOM | 8762 | C | ARG | G | 570 | −7.440 | 43.552 | 44.382 | 1.00 | 12.63 | G | C |
| ATOM | 8763 | O | ARG | G | 570 | −8.293 | 43.818 | 45.224 | 1.00 | 11.46 | G | O |
| ATOM | 8764 | N | PRO | G | 571 | −6.135 | 43.519 | 44.692 | 1.00 | 12.58 | G | N |
| ATOM | 8765 | CD | PRO | G | 571 | −5.012 | 43.318 | 43.753 | 1.00 | 11.63 | G | C |
| ATOM | 8766 | CA | PRO | G | 571 | −5.658 | 43.730 | 46.062 | 1.00 | 11.47 | G | C |
| ATOM | 8767 | CB | PRO | G | 571 | −4.281 | 43.099 | 46.046 | 1.00 | 10.76 | G | C |
| ATOM | 8768 | CG | PRO | G | 571 | −3.776 | 43.461 | 44.645 | 1.00 | 12.50 | G | C |
| ATOM | 8769 | C | PRO | G | 571 | −5.562 | 45.181 | 46.521 | 1.00 | 14.91 | G | C |
| ATOM | 8770 | O | PRO | G | 571 | −5.576 | 46.130 | 45.712 | 1.00 | 12.93 | G | O |
| ATOM | 8771 | N | HIS | G | 572 | −5.475 | 45.331 | 47.843 | 1.00 | 12.43 | G | N |
| ATOM | 8772 | CA | HIS | G | 572 | −5.271 | 46.632 | 48.463 | 1.00 | 11.52 | G | C |
| ATOM | 8773 | CB | HIS | G | 572 | −5.448 | 46.514 | 49.975 | 1.00 | 8.44 | G | C |
| ATOM | 8774 | CG | HIS | G | 572 | −6.867 | 46.648 | 50.425 | 1.00 | 7.38 | G | C |
| ATOM | 8775 | CD2 | HIS | G | 572 | −7.445 | 47.477 | 51.329 | 1.00 | 7.89 | G | C |
| ATOM | 8776 | ND1 | HIS | G | 572 | −7.883 | 45.878 | 49.904 | 1.00 | 6.01 | G | N |
| ATOM | 8777 | CE1 | HIS | G | 572 | −9.026 | 46.226 | 50.466 | 1.00 | 7.11 | G | C |
| ATOM | 8778 | NE2 | HIS | G | 572 | −8.788 | 47.194 | 51.335 | 1.00 | 7.43 | G | N |
| ATOM | 8779 | C | HIS | G | 572 | −3.801 | 46.867 | 48.131 | 1.00 | 8.42 | G | C |
| ATOM | 8780 | O | HIS | G | 572 | −2.984 | 45.962 | 48.319 | 1.00 | 11.13 | G | O |
| ATOM | 8781 | N | CYS | G | 573 | −3.443 | 48.047 | 47.642 | 1.00 | 8.63 | G | N |
| ATOM | 8782 | CA | CYS | G | 573 | −2.049 | 48.263 | 47.277 | 1.00 | 8.74 | G | C |
| ATOM | 8783 | CB | CYS | G | 573 | −1.813 | 47.715 | 45.871 | 1.00 | 6.82 | G | C |
| ATOM | 8784 | SG | CYS | G | 573 | −0.104 | 47.630 | 45.356 | 1.00 | 16.34 | G | S |
| ATOM | 8785 | C | CYS | G | 573 | −1.657 | 49.717 | 47.315 | 1.00 | 9.42 | G | C |
| ATOM | 8786 | O | CYS | G | 573 | −2.395 | 50.573 | 46.836 | 1.00 | 12.66 | G | O |
| ATOM | 8787 | N | GLY | G | 574 | −0.493 | 49.996 | 47.885 | 1.00 | 9.39 | G | N |
| ATOM | 8788 | CA | GLY | G | 574 | −0.011 | 51.367 | 47.940 | 1.00 | 12.77 | G | C |
| ATOM | 8789 | C | GLY | G | 574 | −0.581 | 52.275 | 49.016 | 1.00 | 14.24 | G | C |
| ATOM | 8790 | O | GLY | G | 574 | −0.367 | 53.483 | 48.983 | 1.00 | 15.25 | G | O |
| ATOM | 8791 | N | GLU | G | 575 | −1.326 | 51.716 | 49.963 | 1.00 | 15.73 | G | N |
| ATOM | 8792 | CA | GLU | G | 575 | −1.866 | 52.533 | 51.037 | 1.00 | 16.16 | G | C |
| ATOM | 8793 | CB | GLU | G | 575 | −2.846 | 51.752 | 51.887 | 1.00 | 14.31 | G | C |
| ATOM | 8794 | CG | GLU | G | 575 | −3.489 | 52.606 | 52.917 | 1.00 | 13.91 | G | C |
| ATOM | 8795 | CD | GLU | G | 575 | −4.498 | 51.840 | 53.687 | 1.00 | 15.91 | G | C |
| ATOM | 8796 | OE1 | GLU | G | 575 | −5.454 | 52.448 | 54.200 | 1.00 | 22.17 | G | O |
| ATOM | 8797 | OE2 | GLU | G | 575 | −4.338 | 50.613 | 53.771 | 1.00 | 19.82 | G | O |
| ATOM | 8798 | C | GLU | G | 575 | −0.684 | 52.923 | 51.895 | 1.00 | 16.61 | G | C |
| ATOM | 8799 | O | GLU | G | 575 | −0.653 | 54.001 | 52.473 | 1.00 | 18.23 | G | O |
| ATOM | 8800 | N | VAL | G | 576 | 0.282 | 52.019 | 51.981 | 1.00 | 19.04 | G | N |
| ATOM | 8801 | CA | VAL | G | 576 | 1.508 | 52.251 | 52.738 | 1.00 | 19.60 | G | C |
| ATOM | 8802 | CB | VAL | G | 576 | 1.276 | 52.290 | 54.254 | 1.00 | 20.51 | G | C |
| ATOM | 8803 | CG1 | VAL | G | 576 | 0.960 | 53.699 | 54.690 | 1.00 | 26.80 | G | C |
| ATOM | 8804 | CG2 | VAL | G | 576 | 0.167 | 51.344 | 54.636 | 1.00 | 28.90 | G | C |
| ATOM | 8805 | C | VAL | G | 576 | 2.439 | 51.106 | 52.445 | 1.00 | 19.47 | G | C |
| ATOM | 8806 | O | VAL | G | 576 | 2.132 | 50.245 | 51.609 | 1.00 | 17.51 | G | O |
| ATOM | 8807 | N | GLY | G | 577 | 3.573 | 51.082 | 53.137 | 1.00 | 17.93 | G | N |
| ATOM | 8808 | CA | GLY | G | 577 | 4.516 | 50.007 | 52.908 | 1.00 | 18.60 | G | C |
| ATOM | 8809 | C | GLY | G | 577 | 5.458 | 50.360 | 51.775 | 1.00 | 18.53 | G | C |
| ATOM | 8810 | O | GLY | G | 577 | 5.487 | 51.509 | 51.328 | 1.00 | 15.28 | G | O |
| ATOM | 8811 | N | ALA | G | 578 | 6.218 | 49.365 | 51.314 | 1.00 | 19.54 | G | N |
| ATOM | 8812 | CA | ALA | G | 578 | 7.203 | 49.535 | 50.239 | 1.00 | 20.25 | G | C |
| ATOM | 8813 | CB | ALA | G | 578 | 8.125 | 48.310 | 50.198 | 1.00 | 18.44 | G | C |
| ATOM | 8814 | C | ALA | G | 578 | 6.591 | 49.782 | 48.847 | 1.00 | 20.75 | G | C |
| ATOM | 8815 | O | ALA | G | 578 | 5.477 | 49.352 | 48.549 | 1.00 | 21.73 | G | O |
| ATOM | 8816 | N | LEU | G | 579 | 7.338 | 50.478 | 47.999 | 1.00 | 21.68 | G | N |
| ATOM | 8817 | CA | LEU | G | 579 | 6.890 | 50.785 | 46.646 | 1.00 | 22.64 | G | C |
| ATOM | 8818 | CB | LEU | G | 579 | 7.891 | 51.709 | 45.947 | 1.00 | 22.36 | G | C |
| ATOM | 8819 | CG | LEU | G | 579 | 7.798 | 53.193 | 46.284 | 1.00 | 23.72 | G | C |
| ATOM | 8820 | CD1 | LEU | G | 579 | 8.905 | 53.922 | 45.565 | 1.00 | 27.22 | G | C |
| ATOM | 8821 | CD2 | LEU | G | 579 | 6.441 | 53.740 | 45.901 | 1.00 | 23.43 | G | C |
| ATOM | 8822 | C | LEU | G | 579 | 6.786 | 49.501 | 45.856 | 1.00 | 23.81 | G | C |
| ATOM | 8823 | O | LEU | G | 579 | 5.986 | 49.394 | 44.930 | 1.00 | 26.08 | G | O |
| ATOM | 8824 | N | THR | G | 580 | 7.606 | 48.523 | 46.219 | 1.00 | 23.19 | G | N |
| ATOM | 8825 | CA | THR | G | 580 | 7.593 | 47.264 | 45.516 | 1.00 | 22.58 | G | C |
| ATOM | 8826 | CB | THR | G | 580 | 8.595 | 46.281 | 46.119 | 1.00 | 24.73 | G | C |
| ATOM | 8827 | OG1 | THR | G | 580 | 8.268 | 46.052 | 47.489 | 1.00 | 28.29 | G | O |
| ATOM | 8828 | CG2 | THR | G | 580 | 10.007 | 46.840 | 46.022 | 1.00 | 24.53 | G | C |
| ATOM | 8829 | C | THR | G | 580 | 6.202 | 46.657 | 45.543 | 1.00 | 20.72 | G | C |
| ATOM | 8830 | O | THR | G | 580 | 5.912 | 45.743 | 44.780 | 1.00 | 23.58 | G | O |
| ATOM | 8831 | N | HIS | G | 581 | 5.337 | 47.156 | 46.419 | 1.00 | 16.88 | G | N |
| ATOM | 8832 | CA | HIS | G | 581 | 3.981 | 46.633 | 46.464 | 1.00 | 17.51 | G | C |
| ATOM | 8833 | CB | HIS | G | 581 | 3.192 | 47.227 | 47.632 | 1.00 | 18.16 | G | C |
| ATOM | 8834 | CG | HIS | G | 581 | 3.623 | 46.727 | 48.974 | 1.00 | 17.66 | G | C |
| ATOM | 8835 | CD2 | HIS | G | 581 | 4.670 | 45.953 | 49.343 | 1.00 | 16.29 | G | C |
| ATOM | 8836 | ND1 | HIS | G | 581 | 2.957 | 47.052 | 50.136 | 1.00 | 17.24 | G | N |
| ATOM | 8837 | CE1 | HIS | G | 581 | 3.577 | 46.500 | 51.163 | 1.00 | 18.43 | G | C |
| ATOM | 8838 | NE2 | HIS | G | 581 | 4.620 | 45.829 | 50.709 | 1.00 | 17.21 | G | N |
| ATOM | 8839 | C | HIS | G | 581 | 3.272 | 47.011 | 45.176 | 1.00 | 16.90 | G | C |
| ATOM | 8840 | O | HIS | G | 581 | 2.545 | 46.204 | 44.599 | 1.00 | 16.42 | G | O |
| ATOM | 8841 | N | LEU | G | 582 | 3.488 | 48.251 | 44.738 | 1.00 | 15.17 | G | N |
| ATOM | 8842 | CA | LEU | G | 582 | 2.854 | 48.760 | 43.531 | 1.00 | 14.59 | G | C |
| ATOM | 8843 | CB | LEU | G | 582 | 2.958 | 50.288 | 43.508 | 1.00 | 12.29 | G | C |
| ATOM | 8844 | CG | LEU | G | 582 | 1.993 | 50.899 | 44.538 | 1.00 | 8.80 | G | C |
| ATOM | 8845 | CD1 | LEU | G | 582 | 2.468 | 52.258 | 44.924 | 1.00 | 8.07 | G | C |
| ATOM | 8846 | CD2 | LEU | G | 582 | 0.571 | 50.960 | 43.971 | 1.00 | 6.35 | G | C |
| ATOM | 8847 | C | LEU | G | 582 | 3.452 | 48.132 | 42.285 | 1.00 | 15.76 | G | C |
| ATOM | 8848 | O | LEU | G | 582 | 2.757 | 47.908 | 41.288 | 1.00 | 19.04 | G | O |
| ATOM | 8849 | N | MET | G | 583 | 4.742 | 47.828 | 42.352 | 1.00 | 16.66 | G | N |
| ATOM | 8850 | CA | MET | G | 583 | 5.422 | 47.190 | 41.242 | 1.00 | 17.06 | G | C |
| ATOM | 8851 | CB | MET | G | 583 | 6.909 | 47.087 | 41.581 | 1.00 | 18.05 | G | C |
| ATOM | 8852 | CG | MET | G | 583 | 7.775 | 46.479 | 40.498 | 1.00 | 27.24 | G | C |
| ATOM | 8853 | SD | MET | G | 583 | 8.385 | 44.833 | 40.980 | 1.00 | 38.03 | G | S |
| ATOM | 8854 | CE | MET | G | 583 | 7.062 | 43.830 | 40.422 | 1.00 | 30.31 | G | C |
| ATOM | 8855 | C | MET | G | 583 | 4.790 | 45.789 | 41.019 | 1.00 | 18.70 | G | C |
| ATOM | 8856 | O | MET | G | 583 | 4.496 | 45.387 | 39.888 | 1.00 | 17.70 | G | O |
| ATOM | 8857 | N | THR | G | 584 | 4.565 | 45.057 | 42.107 | 1.00 | 15.50 | G | N |
| ATOM | 8858 | CA | THR | G | 584 | 3.990 | 43.714 | 42.028 | 1.00 | 14.44 | G | C |
| ATOM | 8859 | CB | THR | G | 584 | 4.006 | 43.035 | 43.427 | 1.00 | 15.83 | G | C |
| ATOM | 8860 | OG1 | THR | G | 584 | 5.355 | 42.947 | 43.891 | 1.00 | 14.98 | G | O |
| ATOM | 8861 | CG2 | THR | G | 584 | 3.422 | 41.638 | 43.364 | 1.00 | 15.57 | G | C |
| ATOM | 8862 | C | THR | G | 584 | 2.560 | 43.724 | 41.495 | 1.00 | 13.97 | G | C |
| ATOM | 8863 | O | THR | G | 584 | 2.140 | 42.804 | 40.795 | 1.00 | 14.04 | G | O |
| ATOM | 8864 | N | ALA | G | 585 | 1.808 | 44.761 | 41.843 | 1.00 | 14.35 | G | N |
| ATOM | 8865 | CA | ALA | G | 585 | 0.428 | 44.887 | 41.388 | 1.00 | 14.30 | G | C |
| ATOM | 8866 | CB | ALA | G | 585 | −0.290 | 46.001 | 42.158 | 1.00 | 13.86 | G | C |
| ATOM | 8867 | C | ALA | G | 585 | 0.438 | 45.201 | 39.895 | 1.00 | 13.72 | G | C |
| ATOM | 8868 | O | ALA | G | 585 | −0.457 | 44.778 | 39.171 | 1.00 | 13.02 | G | O |
| ATOM | 8869 | N | PHE | G | 586 | 1.443 | 45.955 | 39.449 | 1.00 | 14.96 | G | N |
| ATOM | 8870 | CA | PHE | G | 586 | 1.573 | 46.287 | 38.034 | 1.00 | 14.00 | G | C |
| ATOM | 8871 | CB | PHE | G | 586 | 2.831 | 47.134 | 37.784 | 1.00 | 13.40 | G | C |
| ATOM | 8872 | CG | PHE | G | 586 | 3.049 | 47.489 | 36.321 | 1.00 | 14.84 | G | C |
| ATOM | 8873 | CD1 | PHE | G | 586 | 2.301 | 48.498 | 35.716 | 1.00 | 10.97 | G | C |
| ATOM | 8874 | CD2 | PHE | G | 586 | 3.995 | 46.795 | 35.549 | 1.00 | 15.02 | G | C |
| ATOM | 8875 | CE1 | PHE | G | 586 | 2.489 | 48.804 | 34.375 | 1.00 | 15.43 | G | C |
| ATOM | 8876 | CE2 | PHE | G | 586 | 4.192 | 47.095 | 34.198 | 1.00 | 10.43 | G | C |
| ATOM | 8877 | CZ | PHE | G | 586 | 3.442 | 48.095 | 33.612 | 1.00 | 14.05 | G | C |
| ATOM | 8878 | C | PHE | G | 586 | 1.660 | 44.974 | 37.251 | 1.00 | 14.69 | G | C |
| ATOM | 8879 | O | PHE | G | 586 | 1.083 | 44.851 | 36.173 | 1.00 | 18.16 | G | O |
| ATOM | 8880 | N | MET | G | 587 | 2.366 | 43.993 | 37.804 | 1.00 | 12.34 | G | N |
| ATOM | 8881 | CA | MET | G | 587 | 2.513 | 42.683 | 37.155 | 1.00 | 16.12 | G | C |
| ATOM | 8882 | CB | MET | G | 587 | 3.734 | 41.937 | 37.710 | 1.00 | 14.10 | G | C |
| ATOM | 8883 | CG | MET | G | 587 | 5.073 | 42.583 | 37.504 | 1.00 | 19.03 | G | C |
| ATOM | 8884 | SD | MET | G | 587 | 6.363 | 41.562 | 38.259 | 1.00 | 20.23 | G | S |
| ATOM | 8885 | CE | MET | G | 587 | 6.386 | 40.111 | 37.175 | 1.00 | 17.84 | G | C |
| ATOM | 8886 | C | MET | G | 587 | 1.340 | 41.696 | 37.314 | 1.00 | 17.38 | G | C |
| ATOM | 8887 | O | MET | G | 587 | 1.093 | 40.875 | 36.428 | 1.00 | 20.76 | G | O |
| ATOM | 8888 | N | THR | G | 588 | 0.626 | 41.779 | 38.440 | 1.00 | 16.69 | G | N |
| ATOM | 8889 | CA | THR | G | 588 | −0.408 | 40.797 | 38.780 | 1.00 | 14.42 | G | C |
| ATOM | 8890 | CB | THR | G | 588 | 0.013 | 40.057 | 40.112 | 1.00 | 16.44 | G | C |
| ATOM | 8891 | OG1 | THR | G | 588 | 0.123 | 41.018 | 41.176 | 1.00 | 15.92 | G | O |
| ATOM | 8892 | CG2 | THR | G | 588 | 1.380 | 39.374 | 39.970 | 1.00 | 11.16 | G | C |
| ATOM | 8893 | C | THR | G | 588 | −1.879 | 41.193 | 38.949 | 1.00 | 13.72 | G | C |
| ATOM | 8894 | O | THR | G | 588 | −2.775 | 40.327 | 38.869 | 1.00 | 10.35 | G | O |
| ATOM | 8895 | N | ALA | G | 589 | −2.142 | 42.474 | 39.186 | 1.00 | 12.22 | G | N |
| ATOM | 8896 | CA | ALA | G | 589 | −3.514 | 42.903 | 39.432 | 1.00 | 12.44 | G | C |
| ATOM | 8897 | CB | ALA | G | 589 | −3.537 | 43.782 | 40.692 | 1.00 | 7.33 | G | C |
| ATOM | 8898 | C | ALA | G | 589 | −4.271 | 43.613 | 38.304 | 1.00 | 13.06 | G | C |
| ATOM | 8899 | O | ALA | G | 589 | −3.729 | 44.495 | 37.638 | 1.00 | 15.32 | G | O |
| ATOM | 8900 | N | ASP | G | 590 | −5.534 | 43.232 | 38.113 | 1.00 | 13.37 | G | N |
| ATOM | 8901 | CA | ASP | G | 590 | −6.386 | 43.876 | 37.119 | 1.00 | 15.35 | G | C |
| ATOM | 8902 | CB | ASP | G | 590 | −7.763 | 43.212 | 37.090 | 1.00 | 11.53 | G | C |
| ATOM | 8903 | CG | ASP | G | 590 | −8.711 | 43.875 | 36.085 | 1.00 | 16.83 | G | C |
| ATOM | 8904 | OD1 | ASP | G | 590 | −9.306 | 44.926 | 36.427 | 1.00 | 16.10 | G | O |
| ATOM | 8905 | OD2 | ASP | G | 590 | −8.866 | 43.352 | 34.955 | 1.00 | 12.53 | G | O |
| ATOM | 8906 | C | ASP | G | 590 | −6.515 | 45.362 | 37.521 | 1.00 | 16.96 | G | C |
| ATOM | 8907 | O | ASP | G | 590 | −6.386 | 46.270 | 36.691 | 1.00 | 15.63 | G | O |
| ATOM | 8908 | N | ASN | G | 591 | −6.776 | 45.598 | 38.807 | 1.00 | 18.44 | G | N |
| ATOM | 8909 | CA | ASN | G | 591 | −6.879 | 46.960 | 39.358 | 1.00 | 17.77 | G | C |
| ATOM | 8910 | CB | ASN | G | 591 | −8.257 | 47.604 | 39.044 | 1.00 | 12.39 | G | C |
| ATOM | 8911 | CG | ASN | G | 591 | −9.421 | 46.870 | 39.665 | 1.00 | 15.31 | G | C |
| ATOM | 8912 | OD1 | ASN | G | 591 | −10.119 | 46.092 | 38.994 | 1.00 | 15.94 | G | O |
| ATOM | 8913 | ND2 | ASN | G | 591 | −9.659 | 47.125 | 40.943 | 1.00 | 9.39 | G | N |
| ATOM | 8914 | C | ASN | G | 591 | −6.588 | 46.892 | 40.870 | 1.00 | 15.61 | G | C |
| ATOM | 8915 | O | ASN | G | 591 | −6.463 | 45.802 | 41.422 | 1.00 | 15.16 | G | O |
| ATOM | 8916 | N | ILE | G | 592 | −6.457 | 48.041 | 41.528 | 1.00 | 15.14 | G | N |
| ATOM | 8917 | CA | ILE | G | 592 | −6.143 | 48.058 | 42.959 | 1.00 | 12.44 | G | C |
| ATOM | 8918 | CB | ILE | G | 592 | −4.660 | 48.489 | 43.208 | 1.00 | 11.27 | G | C |
| ATOM | 8919 | CG2 | ILE | G | 592 | −3.691 | 47.535 | 42.517 | 1.00 | 11.11 | G | C |
| ATOM | 8920 | CG1 | ILE | G | 592 | −4.443 | 49.916 | 42.683 | 1.00 | 10.36 | G | C |
| ATOM | 8921 | CD1 | ILE | G | 592 | −3.160 | 50.588 | 43.180 | 1.00 | 4.07 | G | C |
| ATOM | 8922 | C | ILE | G | 592 | −7.010 | 49.019 | 43.758 | 1.00 | 12.67 | G | C |
| ATOM | 8923 | O | ILE | G | 592 | −7.836 | 49.759 | 43.208 | 1.00 | 12.91 | G | O |
| ATOM | 8924 | N | SER | G | 593 | −6.812 | 48.996 | 45.073 | 1.00 | 12.00 | G | N |
| ATOM | 8925 | CA | SER | G | 593 | −7.509 | 49.911 | 45.958 | 1.00 | 10.74 | G | C |
| ATOM | 8926 | CB | SER | G | 593 | −8.371 | 49.140 | 46.948 | 1.00 | 11.31 | G | C |
| ATOM | 8927 | OG | SER | G | 593 | −9.409 | 48.453 | 46.261 | 1.00 | 13.41 | G | O |
| ATOM | 8928 | C | SER | G | 593 | −6.417 | 50.702 | 46.673 | 1.00 | 11.01 | G | C |
| ATOM | 8929 | O | SER | G | 593 | −5.372 | 50.131 | 47.025 | 1.00 | 9.67 | G | O |
| ATOM | 8930 | N | HIS | G | 594 | −6.668 | 52.009 | 46.839 | 1.00 | 9.94 | G | N |
| ATOM | 8931 | CA | HIS | G | 594 | −5.788 | 53.004 | 47.491 | 1.00 | 10.11 | G | C |
| ATOM | 8932 | CB | HIS | G | 594 | −5.057 | 52.424 | 48.713 | 1.00 | 8.01 | G | C |
| ATOM | 8933 | CG | HIS | G | 594 | −5.968 | 52.124 | 49.870 | 1.00 | 10.10 | G | C |
| ATOM | 8934 | CD2 | HIS | G | 594 | −6.308 | 50.949 | 50.461 | 1.00 | 7.24 | G | C |
| ATOM | 8935 | ND1 | HIS | G | 594 | −6.731 | 53.093 | 50.491 | 1.00 | 10.10 | G | N |
| ATOM | 8936 | CE1 | HIS | G | 594 | −7.504 | 52.532 | 51.406 | 1.00 | 7.09 | G | C |
| ATOM | 8937 | NE2 | HIS | G | 594 | −7.267 | 51.232 | 51.407 | 1.00 | 7.66 | G | N |
| ATOM | 8938 | C | HIS | G | 594 | −4.779 | 53.602 | 46.523 | 1.00 | 12.27 | G | C |
| ATOM | 8939 | O | HIS | G | 594 | −5.038 | 54.652 | 45.959 | 1.00 | 13.76 | G | O |
| ATOM | 8940 | N | GLY | G | 595 | −3.630 | 52.952 | 46.344 | 1.00 | 13.04 | G | N |
| ATOM | 8941 | CA | GLY | G | 595 | −2.623 | 53.459 | 45.417 | 1.00 | 12.76 | G | C |
| ATOM | 8942 | C | GLY | G | 595 | −1.931 | 54.774 | 45.772 | 1.00 | 16.88 | G | C |
| ATOM | 8943 | O | GLY | G | 595 | −1.254 | 55.374 | 44.934 | 1.00 | 17.26 | G | O |
| ATOM | 8944 | N | LEU | G | 596 | −2.062 | 55.225 | 47.013 | 1.00 | 17.40 | G | N |
| ATOM | 8945 | CA | LEU | G | 596 | −1.451 | 56.488 | 47.427 | 1.00 | 14.76 | G | C |
| ATOM | 8946 | CB | LEU | G | 596 | −1.756 | 56.750 | 48.906 | 1.00 | 16.20 | G | C |
| ATOM | 8947 | CG | LEU | G | 596 | −3.242 | 56.664 | 49.266 | 1.00 | 15.59 | G | C |
| ATOM | 8948 | CD1 | LEU | G | 596 | −3.425 | 56.587 | 50.764 | 1.00 | 14.76 | G | C |
| ATOM | 8949 | CD2 | LEU | G | 596 | −3.948 | 57.884 | 48.699 | 1.00 | 16.47 | G | C |
| ATOM | 8950 | C | LEU | G | 596 | 0.055 | 56.592 | 47.195 | 1.00 | 13.79 | G | C |
| ATOM | 8951 | O | LEU | G | 596 | 0.537 | 57.645 | 46.788 | 1.00 | 12.91 | G | O |
| ATOM | 8952 | N | ASN | G | 597 | 0.798 | 55.514 | 47.432 | 1.00 | 13.52 | G | N |
| ATOM | 8953 | CA | ASN | G | 597 | 2.249 | 55.559 | 47.261 | 1.00 | 14.05 | G | C |
| ATOM | 8954 | CB | ASN | G | 597 | 2.892 | 54.303 | 47.880 | 1.00 | 14.28 | G | C |
| ATOM | 8955 | CG | ASN | G | 597 | 3.062 | 54.425 | 49.392 | 1.00 | 18.67 | G | C |
| ATOM | 8956 | OD1 | ASN | G | 597 | 2.946 | 55.519 | 49.951 | 1.00 | 19.32 | G | O |
| ATOM | 8957 | ND2 | ASN | G | 597 | 3.332 | 53.303 | 50.061 | 1.00 | 19.96 | G | N |
| ATOM | 8958 | C | ASN | G | 597 | 2.715 | 55.772 | 45.808 | 1.00 | 14.96 | G | C |
| ATOM | 8959 | O | ASN | G | 597 | 3.917 | 55.903 | 45.548 | 1.00 | 12.58 | G | O |
| ATOM | 8960 | N | LEU | G | 598 | 1.783 | 55.822 | 44.860 | 1.00 | 12.09 | G | N |
| ATOM | 8961 | CA | LEU | G | 598 | 2.188 | 56.089 | 43.481 | 1.00 | 15.77 | G | C |
| ATOM | 8962 | CB | LEU | G | 598 | 0.981 | 56.010 | 42.529 | 1.00 | 14.48 | G | C |
| ATOM | 8963 | CG | LEU | G | 598 | 0.541 | 54.578 | 42.200 | 1.00 | 15.48 | G | C |
| ATOM | 8964 | CD1 | LEU | G | 598 | −0.758 | 54.582 | 41.397 | 1.00 | 12.90 | G | C |
| ATOM | 8965 | CD2 | LEU | G | 598 | 1.668 | 53.883 | 41.431 | 1.00 | 12.68 | G | C |
| ATOM | 8966 | C | LEU | G | 598 | 2.804 | 57.496 | 43.436 | 1.00 | 15.28 | G | C |
| ATOM | 8967 | O | LEU | G | 598 | 3.620 | 57.819 | 42.566 | 1.00 | 14.80 | G | O |
| ATOM | 8968 | N | LYS | G | 599 | 2.402 | 58.321 | 44.392 | 1.00 | 13.56 | G | N |
| ATOM | 8969 | CA | LYS | G | 599 | 2.885 | 59.687 | 44.513 | 1.00 | 16.62 | G | C |
| ATOM | 8970 | CB | LYS | G | 599 | 2.236 | 60.357 | 45.720 | 1.00 | 20.34 | G | C |
| ATOM | 8971 | CG | LYS | G | 599 | 1.002 | 61.132 | 45.376 | 1.00 | 30.22 | G | C |
| ATOM | 8972 | CD | LYS | G | 599 | 1.305 | 62.629 | 45.237 | 1.00 | 38.49 | G | C |
| ATOM | 8973 | CE | LYS | G | 599 | 0.720 | 63.212 | 43.946 | 1.00 | 38.26 | G | C |
| ATOM | 8974 | NZ | LYS | G | 599 | 1.769 | 63.348 | 42.876 | 1.00 | 43.94 | G | N |
| ATOM | 8975 | C | LYS | G | 599 | 4.391 | 59.739 | 44.698 | 1.00 | 17.19 | G | C |
| ATOM | 8976 | O | LYS | G | 599 | 5.025 | 60.734 | 44.376 | 1.00 | 16.88 | G | O |
| ATOM | 8977 | N | LYS | G | 600 | 4.954 | 58.663 | 45.233 | 1.00 | 18.32 | G | N |
| ATOM | 8978 | CA | LYS | G | 600 | 6.384 | 58.591 | 45.492 | 1.00 | 20.09 | G | C |
| ATOM | 8979 | CB | LYS | G | 600 | 6.645 | 57.789 | 46.764 | 1.00 | 21.22 | G | C |
| ATOM | 8980 | CG | LYS | G | 600 | 6.045 | 58.369 | 48.035 | 1.00 | 24.84 | G | C |
| ATOM | 8981 | CD | LYS | G | 600 | 6.266 | 57.387 | 49.180 | 1.00 | 28.11 | G | C |
| ATOM | 8982 | CE | LYS | G | 600 | 5.514 | 57.788 | 50.440 | 1.00 | 33.63 | G | C |
| ATOM | 8983 | NZ | LYS | G | 600 | 5.750 | 56.797 | 51.541 | 1.00 | 36.32 | G | N |
| ATOM | 8984 | C | LYS | G | 600 | 7.196 | 57.958 | 44.372 | 1.00 | 20.76 | G | C |
| ATOM | 8985 | O | LYS | G | 600 | 8.417 | 57.882 | 44.468 | 1.00 | 21.62 | G | O |
| ATOM | 8986 | N | SER | G | 601 | 6.536 | 57.483 | 43.324 | 1.00 | 17.43 | G | N |
| ATOM | 8987 | CA | SER | G | 601 | 7.273 | 56.842 | 42.235 | 1.00 | 17.95 | G | C |
| ATOM | 8988 | CB | SER | G | 601 | 7.067 | 55.333 | 42.270 | 1.00 | 13.72 | G | C |
| ATOM | 8989 | OG | SER | G | 601 | 7.843 | 54.724 | 41.264 | 1.00 | 18.72 | G | O |
| ATOM | 8990 | C | SER | G | 601 | 6.827 | 57.363 | 40.881 | 1.00 | 16.19 | G | C |
| ATOM | 8991 | O | SER | G | 601 | 5.778 | 56.964 | 40.376 | 1.00 | 15.70 | G | O |
| ATOM | 8992 | N | PRO | G | 602 | 7.635 | 58.238 | 40.262 | 1.00 | 16.50 | G | N |
| ATOM | 8993 | CD | PRO | G | 602 | 8.956 | 58.695 | 40.722 | 1.00 | 15.05 | G | C |
| ATOM | 8994 | CA | PRO | G | 602 | 7.284 | 58.799 | 38.950 | 1.00 | 16.28 | G | C |
| ATOM | 8995 | CB | PRO | G | 602 | 8.448 | 59.746 | 38.631 | 1.00 | 13.81 | G | C |
| ATOM | 8996 | CG | PRO | G | 602 | 9.587 | 59.225 | 39.457 | 1.00 | 17.96 | G | C |
| ATOM | 8997 | C | PRO | G | 602 | 7.131 | 57.694 | 37.905 | 1.00 | 14.68 | G | C |
| ATOM | 8998 | O | PRO | G | 602 | 6.191 | 57.711 | 37.110 | 1.00 | 16.42 | G | O |
| ATOM | 8999 | N | VAL | G | 603 | 8.050 | 56.733 | 37.923 | 1.00 | 14.38 | G | N |
| ATOM | 9000 | CA | VAL | G | 603 | 8.010 | 55.629 | 36.975 | 1.00 | 14.69 | G | C |
| ATOM | 9001 | CB | VAL | G | 603 | 9.299 | 54.739 | 37.099 | 1.00 | 15.01 | G | C |
| ATOM | 9002 | CG1 | VAL | G | 603 | 9.319 | 53.656 | 35.991 | 1.00 | 13.98 | G | C |
| ATOM | 9003 | CG2 | VAL | G | 603 | 10.552 | 55.608 | 36.976 | 1.00 | 10.61 | G | C |
| ATOM | 9004 | C | VAL | G | 603 | 6.736 | 54.781 | 37.144 | 1.00 | 15.62 | G | C |
| ATOM | 9005 | O | VAL | G | 603 | 6.002 | 54.557 | 36.168 | 1.00 | 15.05 | G | O |
| ATOM | 9006 | N | LEU | G | 604 | 6.453 | 54.329 | 38.369 | 1.00 | 13.96 | G | N |
| ATOM | 9007 | CA | LEU | G | 604 | 5.264 | 53.513 | 38.604 | 1.00 | 13.26 | G | C |
| ATOM | 9008 | CB | LEU | G | 604 | 5.277 | 52.944 | 40.025 | 1.00 | 13.07 | G | C |
| ATOM | 9009 | CG | LEU | G | 604 | 6.043 | 51.631 | 40.231 | 1.00 | 12.71 | G | C |
| ATOM | 9010 | CD1 | LEU | G | 604 | 6.221 | 51.352 | 41.728 | 1.00 | 13.62 | G | C |
| ATOM | 9011 | CD2 | LEU | G | 604 | 5.290 | 50.492 | 39.576 | 1.00 | 10.47 | G | C |
| ATOM | 9012 | C | LEU | G | 604 | 3.974 | 54.303 | 38.370 | 1.00 | 13.35 | G | C |
| ATOM | 9013 | O | LEU | G | 604 | 3.006 | 53.784 | 37.808 | 1.00 | 15.37 | G | O |
| ATOM | 9014 | N | GLN | G | 605 | 3.958 | 55.560 | 38.794 | 1.00 | 12.02 | G | N |
| ATOM | 9015 | CA | GLN | G | 605 | 2.789 | 56.394 | 38.596 | 1.00 | 11.83 | G | C |
| ATOM | 9016 | CB | GLN | G | 605 | 2.988 | 57.759 | 39.258 | 1.00 | 11.08 | G | C |
| ATOM | 9017 | CG | GLN | G | 605 | 1.780 | 58.686 | 39.109 | 1.00 | 8.69 | G | C |
| ATOM | 9018 | CD | GLN | G | 605 | 2.018 | 60.049 | 39.723 | 1.00 | 13.32 | G | C |
| ATOM | 9019 | OE1 | GLN | G | 605 | 2.809 | 60.191 | 40.663 | 1.00 | 17.15 | G | O |
| ATOM | 9020 | NE2 | GLN | G | 605 | 1.341 | 61.055 | 39.205 | 1.00 | 7.86 | G | N |
| ATOM | 9021 | C | GLN | G | 605 | 2.518 | 56.593 | 37.102 | 1.00 | 11.27 | G | C |
| ATOM | 9022 | O | GLN | G | 605 | 1.368 | 56.588 | 36.677 | 1.00 | 11.43 | G | O |
| ATOM | 9023 | N | TYR | G | 606 | 3.581 | 56.792 | 36.318 | 1.00 | 12.11 | G | N |
| ATOM | 9024 | CA | TYR | G | 606 | 3.447 | 56.976 | 34.869 | 1.00 | 12.96 | G | C |
| ATOM | 9025 | CB | TYR | G | 606 | 4.771 | 57.462 | 34.262 | 1.00 | 10.20 | G | C |
| ATOM | 9026 | CG | TYR | G | 606 | 4.638 | 57.979 | 32.854 | 1.00 | 12.80 | G | C |
| ATOM | 9027 | CD1 | TYR | G | 606 | 3.748 | 59.014 | 32.544 | 1.00 | 13.75 | G | C |
| ATOM | 9028 | CE1 | TYR | G | 606 | 3.633 | 59.508 | 31.228 | 1.00 | 13.51 | G | C |
| ATOM | 9029 | CD2 | TYR | G | 606 | 5.411 | 57.443 | 31.822 | 1.00 | 14.89 | G | C |
| ATOM | 9030 | CE2 | TYR | G | 606 | 5.309 | 57.925 | 30.505 | 1.00 | 14.56 | G | C |
| ATOM | 9031 | CZ | TYR | G | 606 | 4.425 | 58.954 | 30.213 | 1.00 | 14.40 | G | C |
| ATOM | 9032 | OH | TYR | G | 606 | 4.359 | 59.438 | 28.920 | 1.00 | 14.32 | G | O |
| ATOM | 9033 | C | TYR | G | 606 | 3.006 | 55.668 | 34.209 | 1.00 | 11.13 | G | C |
| ATOM | 9034 | O | TYR | G | 606 | 2.179 | 55.676 | 33.309 | 1.00 | 12.88 | G | O |
| ATOM | 9035 | N | LEU | G | 607 | 3.546 | 54.547 | 34.685 | 1.00 | 11.84 | G | N |
| ATOM | 9036 | CA | LEU | G | 607 | 3.195 | 53.239 | 34.146 | 1.00 | 11.11 | G | C |
| ATOM | 9037 | CB | LEU | G | 607 | 4.086 | 52.148 | 34.751 | 1.00 | 10.33 | G | C |
| ATOM | 9038 | CG | LEU | G | 607 | 5.489 | 52.027 | 34.142 | 1.00 | 12.35 | G | C |
| ATOM | 9039 | CD1 | LEU | G | 607 | 6.317 | 50.997 | 34.889 | 1.00 | 8.14 | G | C |
| ATOM | 9040 | CD2 | LEU | G | 607 | 5.360 | 51.616 | 32.696 | 1.00 | 12.42 | G | C |
| ATOM | 9041 | C | LEU | G | 607 | 1.740 | 52.928 | 34.418 | 1.00 | 9.45 | G | C |
| ATOM | 9042 | O | LEU | G | 607 | 1.083 | 52.285 | 33.602 | 1.00 | 11.43 | G | O |
| ATOM | 9043 | N | PHE | G | 608 | 1.224 | 53.378 | 35.559 | 1.00 | 9.03 | G | N |
| ATOM | 9044 | CA | PHE | G | 608 | −0.184 | 53.123 | 35.883 | 1.00 | 8.32 | G | C |
| ATOM | 9045 | CB | PHE | G | 608 | −0.476 | 53.439 | 37.361 | 1.00 | 8.35 | G | C |
| ATOM | 9046 | CG | PHE | G | 608 | −0.312 | 52.254 | 38.284 | 1.00 | 10.44 | G | C |
| ATOM | 9047 | CD1 | PHE | G | 608 | 0.925 | 51.624 | 38.423 | 1.00 | 8.62 | G | C |
| ATOM | 9048 | CD2 | PHE | G | 608 | −1.398 | 51.751 | 38.993 | 1.00 | 7.34 | G | C |
| ATOM | 9049 | CE1 | PHE | G | 608 | 1.068 | 50.514 | 39.246 | 1.00 | 7.29 | G | C |
| ATOM | 9050 | CE2 | PHE | G | 608 | −1.258 | 50.635 | 39.820 | 1.00 | 5.81 | G | C |
| ATOM | 9051 | CZ | PHE | G | 608 | −0.028 | 50.019 | 39.945 | 1.00 | 7.47 | G | C |
| ATOM | 9052 | C | PHE | G | 608 | −1.075 | 53.985 | 34.975 | 1.00 | 8.74 | G | C |
| ATOM | 9053 | O | PHE | G | 608 | −2.203 | 53.614 | 34.669 | 1.00 | 9.48 | G | O |
| ATOM | 9054 | N | PHE | G | 609 | −0.576 | 55.154 | 34.579 | 1.00 | 9.43 | G | N |
| ATOM | 9055 | CA | PHE | G | 609 | −1.316 | 56.027 | 33.665 | 1.00 | 10.38 | G | C |
| ATOM | 9056 | CB | PHE | G | 609 | −0.653 | 57.409 | 33.583 | 1.00 | 12.43 | G | C |
| ATOM | 9057 | CG | PHE | G | 609 | −1.138 | 58.234 | 32.415 | 1.00 | 12.29 | G | C |
| ATOM | 9058 | CD1 | PHE | G | 609 | −0.416 | 58.283 | 31.220 | 1.00 | 10.08 | G | C |
| ATOM | 9059 | CD2 | PHE | G | 609 | −2.370 | 58.880 | 32.475 | 1.00 | 9.31 | G | C |
| ATOM | 9060 | CE1 | PHE | G | 609 | −0.927 | 58.955 | 30.104 | 1.00 | 7.13 | G | C |
| ATOM | 9061 | CE2 | PHE | G | 609 | −2.882 | 59.551 | 31.363 | 1.00 | 5.91 | G | C |
| ATOM | 9062 | CZ | PHE | G | 609 | −2.161 | 59.585 | 30.180 | 1.00 | 6.63 | G | C |
| ATOM | 9063 | C | PHE | G | 609 | −1.285 | 55.390 | 32.256 | 1.00 | 10.79 | G | C |
| ATOM | 9064 | O | PHE | G | 609 | −2.306 | 55.278 | 31.577 | 1.00 | 10.86 | G | O |
| ATOM | 9065 | N | LEU | G | 610 | −0.098 | 54.983 | 31.823 | 1.00 | 9.63 | G | N |
| ATOM | 9066 | CA | LEU | G | 610 | 0.059 | 54.371 | 30.505 | 1.00 | 12.82 | G | C |
| ATOM | 9067 | CB | LEU | G | 610 | 1.538 | 54.021 | 30.247 | 1.00 | 9.10 | G | C |
| ATOM | 9068 | CG | LEU | G | 610 | 2.471 | 55.215 | 30.040 | 1.00 | 10.11 | G | C |
| ATOM | 9069 | CD1 | LEU | G | 610 | 3.886 | 54.689 | 29.836 | 1.00 | 8.63 | G | C |
| ATOM | 9070 | CD2 | LEU | G | 610 | 1.998 | 56.068 | 28.842 | 1.00 | 7.05 | G | C |
| ATOM | 9071 | C | LEU | G | 610 | −0.813 | 53.125 | 30.311 | 1.00 | 11.78 | G | C |
| ATOM | 9072 | O | LEU | G | 610 | −1.435 | 52.954 | 29.262 | 1.00 | 13.98 | G | O |
| ATOM | 9073 | N | ALA | G | 611 | −0.847 | 52.253 | 31.312 | 1.00 | 10.39 | G | N |
| ATOM | 9074 | CA | ALA | G | 611 | −1.653 | 51.040 | 31.245 | 1.00 | 9.08 | G | C |
| ATOM | 9075 | CB | ALA | G | 611 | −1.001 | 49.939 | 32.074 | 1.00 | 10.16 | G | C |
| ATOM | 9076 | C | ALA | G | 611 | −3.084 | 51.277 | 31.721 | 1.00 | 10.52 | G | C |
| ATOM | 9077 | O | ALA | G | 611 | −3.901 | 50.368 | 31.718 | 1.00 | 13.84 | G | O |
| ATOM | 9078 | N | GLN | G | 612 | −3.391 | 52.507 | 32.113 | 1.00 | 11.33 | G | N |
| ATOM | 9079 | CA | GLN | G | 612 | −4.721 | 52.865 | 32.602 | 1.00 | 11.26 | G | C |
| ATOM | 9080 | CB | GLN | G | 612 | −5.696 | 53.002 | 31.428 | 1.00 | 11.19 | G | C |
| ATOM | 9081 | CG | GLN | G | 612 | −5.550 | 54.313 | 30.665 | 1.00 | 10.16 | G | C |
| ATOM | 9082 | CD | GLN | G | 612 | −5.912 | 55.525 | 31.495 | 1.00 | 14.99 | G | C |
| ATOM | 9083 | OE1 | GLN | G | 612 | −7.082 | 55.786 | 31.733 | 1.00 | 17.25 | G | O |
| ATOM | 9084 | NE2 | GLN | G | 612 | −4.903 | 56.277 | 31.939 | 1.00 | 15.62 | G | N |
| ATOM | 9085 | C | GLN | G | 612 | −5.267 | 51.870 | 33.636 | 1.00 | 11.69 | G | C |
| ATOM | 9086 | O | GLN | G | 612 | −6.415 | 51.425 | 33.563 | 1.00 | 10.71 | G | O |
| ATOM | 9087 | N | ILE | G | 613 | −4.431 | 51.537 | 34.613 | 1.00 | 12.37 | G | N |
| ATOM | 9088 | CA | ILE | G | 613 | −4.802 | 50.601 | 35.674 | 1.00 | 11.47 | G | C |
| ATOM | 9089 | CB | ILE | G | 613 | −3.544 | 50.187 | 36.483 | 1.00 | 9.80 | G | C |
| ATOM | 9090 | CG2 | ILE | G | 613 | −3.930 | 49.196 | 37.596 | 1.00 | 10.10 | G | C |
| ATOM | 9091 | CG1 | ILE | G | 613 | −2.504 | 49.591 | 35.528 | 1.00 | 7.95 | G | C |
| ATOM | 9092 | CD1 | ILE | G | 613 | −1.206 | 49.165 | 36.162 | 1.00 | 2.26 | G | C |
| ATOM | 9093 | C | ILE | G | 613 | −5.800 | 51.281 | 36.613 | 1.00 | 11.39 | G | C |
| ATOM | 9094 | O | ILE | G | 613 | −5.467 | 52.286 | 37.237 | 1.00 | 13.20 | G | O |
| ATOM | 9095 | N | PRO | G | 614 | −7.034 | 50.750 | 36.730 | 1.00 | 9.63 | G | N |
| ATOM | 9096 | CD | PRO | G | 614 | −7.623 | 49.563 | 36.096 | 1.00 | 6.70 | G | C |
| ATOM | 9097 | CA | PRO | G | 614 | −7.985 | 51.412 | 37.632 | 1.00 | 10.78 | G | C |
| ATOM | 9098 | CB | PRO | G | 614 | −9.301 | 50.660 | 37.405 | 1.00 | 8.89 | G | C |
| ATOM | 9099 | CG | PRO | G | 614 | −9.087 | 49.876 | 36.133 | 1.00 | 8.96 | G | C |
| ATOM | 9100 | C | PRO | G | 614 | −7.552 | 51.393 | 39.107 | 1.00 | 11.37 | G | C |
| ATOM | 9101 | O | PRO | G | 614 | −6.962 | 50.421 | 39.601 | 1.00 | 9.02 | G | O |
| ATOM | 9102 | N | ILE | G | 615 | −7.850 | 52.491 | 39.793 | 1.00 | 11.64 | G | N |
| ATOM | 9103 | CA | ILE | G | 615 | −7.526 | 52.648 | 41.205 | 1.00 | 10.95 | G | C |
| ATOM | 9104 | CB | ILE | G | 615 | −6.381 | 53.680 | 41.410 | 1.00 | 11.29 | G | C |
| ATOM | 9105 | CG2 | ILE | G | 615 | −6.029 | 53.803 | 42.901 | 1.00 | 7.92 | G | C |
| ATOM | 9106 | CG1 | ILE | G | 615 | −5.146 | 53.257 | 40.607 | 1.00 | 9.82 | G | C |
| ATOM | 9107 | CD1 | ILE | G | 615 | −4.288 | 54.426 | 40.162 | 1.00 | 9.86 | G | C |
| ATOM | 9108 | C | ILE | G | 615 | −8.763 | 53.142 | 41.967 | 1.00 | 13.76 | G | C |
| ATOM | 9109 | O | ILE | G | 615 | −9.290 | 54.231 | 41.669 | 1.00 | 9.79 | G | O |
| ATOM | 9110 | N | ALA | G | 616 | −9.236 | 52.329 | 42.924 | 1.00 | 10.84 | G | N |
| ATOM | 9111 | CA | ALA | G | 616 | −10.377 | 52.709 | 43.767 | 1.00 | 11.84 | G | C |
| ATOM | 9112 | CB | ALA | G | 616 | −11.125 | 51.460 | 44.269 | 1.00 | 8.53 | G | C |
| ATOM | 9113 | C | ALA | G | 616 | −9.757 | 53.462 | 44.957 | 1.00 | 10.99 | G | C |
| ATOM | 9114 | O | ALA | G | 616 | −8.994 | 52.878 | 45.731 | 1.00 | 11.08 | G | O |
| ATOM | 9115 | N | MET | G | 617 | −10.062 | 54.748 | 45.093 | 1.00 | 10.07 | G | N |
| ATOM | 9116 | CA | MET | G | 617 | −9.505 | 55.543 | 46.195 | 1.00 | 10.60 | G | C |
| ATOM | 9117 | CB | MET | G | 617 | −8.888 | 56.838 | 45.651 | 1.00 | 8.14 | G | C |
| ATOM | 9118 | CG | MET | G | 617 | −7.900 | 56.609 | 44.508 | 1.00 | 11.22 | G | C |
| ATOM | 9119 | SD | MET | G | 617 | −6.680 | 57.936 | 44.327 | 1.00 | 16.19 | G | S |
| ATOM | 9120 | CE | MET | G | 617 | −7.466 | 58.894 | 43.256 | 1.00 | 19.21 | G | C |
| ATOM | 9121 | C | MET | G | 617 | −10.583 | 55.865 | 47.234 | 1.00 | 11.58 | G | C |
| ATOM | 9122 | O | MET | G | 617 | −11.776 | 55.941 | 46.894 | 1.00 | 12.36 | G | O |
| ATOM | 9123 | N | SER | G | 618 | −10.156 | 56.060 | 48.486 | 1.00 | 12.33 | G | N |
| ATOM | 9124 | CA | SER | G | 618 | −11.054 | 56.346 | 49.622 | 1.00 | 11.74 | G | C |
| ATOM | 9125 | CB | SER | G | 618 | −11.159 | 55.103 | 50.521 | 1.00 | 13.60 | G | C |
| ATOM | 9126 | OG | SER | G | 618 | −11.476 | 53.951 | 49.771 | 1.00 | 15.42 | G | O |
| ATOM | 9127 | C | SER | G | 618 | −10.523 | 57.503 | 50.470 | 1.00 | 12.77 | G | C |
| ATOM | 9128 | O | SER | G | 618 | −9.953 | 57.280 | 51.542 | 1.00 | 14.62 | G | O |
| ATOM | 9129 | N | PRO | G | 619 | −10.683 | 58.751 | 50.003 | 1.00 | 12.61 | G | N |
| ATOM | 9130 | CD | PRO | G | 619 | −11.289 | 59.149 | 48.716 | 1.00 | 11.13 | G | C |
| ATOM | 9131 | CA | PRO | G | 619 | −10.193 | 59.912 | 50.763 | 1.00 | 10.94 | G | C |
| ATOM | 9132 | CB | PRO | G | 619 | −10.577 | 61.106 | 49.882 | 1.00 | 11.79 | G | C |
| ATOM | 9133 | CG | PRO | G | 619 | −10.687 | 60.507 | 48.477 | 1.00 | 11.41 | G | C |
| ATOM | 9134 | C | PRO | G | 619 | −10.674 | 60.077 | 52.213 | 1.00 | 12.21 | G | C |
| ATOM | 9135 | O | PRO | G | 619 | −9.905 | 60.529 | 53.057 | 1.00 | 12.88 | G | O |
| ATOM | 9136 | N | LEU | G | 620 | −11.926 | 59.742 | 52.511 | 1.00 | 8.78 | G | N |
| ATOM | 9137 | CA | LEU | G | 620 | −12.408 | 59.865 | 53.891 | 1.00 | 13.07 | G | C |
| ATOM | 9138 | CB | LEU | G | 620 | −13.927 | 59.674 | 53.957 | 1.00 | 10.21 | G | C |
| ATOM | 9139 | CG | LEU | G | 620 | −14.738 | 60.925 | 53.566 | 1.00 | 15.61 | G | C |
| ATOM | 9140 | CD1 | LEU | G | 620 | −16.230 | 60.616 | 53.606 | 1.00 | 11.46 | G | C |
| ATOM | 9141 | CD2 | LEU | G | 620 | −14.404 | 62.087 | 54.524 | 1.00 | 15.81 | G | C |
| ATOM | 9142 | C | LEU | G | 620 | −11.701 | 58.841 | 54.805 | 1.00 | 13.87 | G | C |
| ATOM | 9143 | O | LEU | G | 620 | −11.261 | 59.172 | 55.900 | 1.00 | 12.24 | G | O |
| ATOM | 9144 | N | SER | G | 621 | −11.591 | 57.600 | 54.347 | 1.00 | 14.08 | G | N |
| ATOM | 9145 | CA | SER | G | 621 | −10.904 | 56.572 | 55.110 | 1.00 | 15.10 | G | C |
| ATOM | 9146 | CB | SER | G | 621 | −11.035 | 55.228 | 54.394 | 1.00 | 15.67 | G | C |
| ATOM | 9147 | OG | SER | G | 621 | −10.017 | 54.338 | 54.790 | 1.00 | 16.88 | G | O |
| ATOM | 9148 | C | SER | G | 621 | −9.427 | 56.963 | 55.270 | 1.00 | 16.81 | G | C |
| ATOM | 9149 | O | SER | G | 621 | −8.890 | 56.905 | 56.374 | 1.00 | 16.21 | G | O |
| ATOM | 9150 | N | ASN | G | 622 | −8.781 | 57.376 | 54.174 | 1.00 | 15.98 | G | N |
| ATOM | 9151 | CA | ASN | G | 622 | −7.375 | 57.783 | 54.215 | 1.00 | 15.99 | G | C |
| ATOM | 9152 | CB | ASN | G | 622 | −6.896 | 58.271 | 52.846 | 1.00 | 15.85 | G | C |
| ATOM | 9153 | CG | ASN | G | 622 | −6.891 | 57.186 | 51.783 | 1.00 | 15.83 | G | C |
| ATOM | 9154 | OD1 | ASN | G | 622 | −6.891 | 57.492 | 50.603 | 1.00 | 16.42 | G | O |
| ATOM | 9155 | ND2 | ASN | G | 622 | −6.884 | 55.930 | 52.192 | 1.00 | 17.09 | G | N |
| ATOM | 9156 | C | ASN | G | 622 | −7.205 | 58.943 | 55.199 | 1.00 | 16.44 | G | C |
| ATOM | 9157 | O | ASN | G | 622 | −6.219 | 59.028 | 55.918 | 1.00 | 16.23 | G | O |
| ATOM | 9158 | N | ASN | G | 623 | −8.168 | 59.852 | 55.200 | 1.00 | 16.93 | G | N |
| ATOM | 9159 | CA | ASN | G | 623 | −8.115 | 61.009 | 56.079 | 1.00 | 22.64 | G | C |
| ATOM | 9160 | CB | ASN | G | 623 | −9.320 | 61.919 | 55.815 | 1.00 | 20.37 | G | C |
| ATOM | 9161 | CG | ASN | G | 623 | −9.443 | 63.076 | 56.814 | 1.00 | 19.83 | G | C |
| ATOM | 9162 | OD1 | ASN | G | 623 | −10.439 | 63.173 | 57.531 | 1.00 | 21.60 | G | O |
| ATOM | 9163 | ND2 | ASN | G | 623 | −8.453 | 63.959 | 56.848 | 1.00 | 12.02 | G | N |
| ATOM | 9164 | C | ASN | G | 623 | −8.087 | 60.539 | 57.522 | 1.00 | 28.88 | G | C |
| ATOM | 9165 | O | ASN | G | 623 | −7.389 | 61.119 | 58.347 | 1.00 | 32.39 | G | O |
| ATOM | 9166 | N | SER | G | 624 | −8.811 | 59.462 | 57.814 | 1.00 | 33.35 | G | N |
| ATOM | 9167 | CA | SER | G | 624 | −8.861 | 58.926 | 59.165 | 1.00 | 39.13 | G | C |
| ATOM | 9168 | CB | SER | G | 624 | −9.843 | 57.774 | 59.239 | 1.00 | 40.99 | G | C |
| ATOM | 9169 | OG | SER | G | 624 | −10.981 | 58.166 | 59.986 | 1.00 | 44.19 | G | O |
| ATOM | 9170 | C | SER | G | 624 | −7.529 | 58.491 | 59.776 | 1.00 | 42.68 | G | C |
| ATOM | 9171 | O | SER | G | 624 | −7.460 | 58.251 | 60.979 | 1.00 | 46.21 | G | O |
| ATOM | 9172 | N | LEU | G | 625 | −6.480 | 58.377 | 58.969 | 1.00 | 45.34 | G | N |
| ATOM | 9173 | CA | LEU | G | 625 | −5.169 | 58.028 | 59.510 | 1.00 | 47.09 | G | C |
| ATOM | 9174 | CB | LEU | G | 625 | −5.020 | 56.513 | 59.671 | 1.00 | 49.82 | G | C |
| ATOM | 9175 | CG | LEU | G | 625 | −4.405 | 56.022 | 61.000 | 1.00 | 54.89 | G | C |
| ATOM | 9176 | CD1 | LEU | G | 625 | −3.360 | 54.941 | 60.716 | 1.00 | 54.52 | G | C |
| ATOM | 9177 | CD2 | LEU | G | 625 | −3.779 | 57.190 | 61.779 | 1.00 | 54.40 | G | C |
| ATOM | 9178 | C | LEU | G | 625 | −4.035 | 58.559 | 58.641 | 1.00 | 47.79 | G | C |
| ATOM | 9179 | O | LEU | G | 625 | −3.613 | 59.715 | 58.757 | 1.00 | 47.29 | G | O |
| ATOM | 9180 | N | PHE | G | 626 | −3.559 | 57.693 | 57.762 | 1.00 | 47.32 | G | N |
| ATOM | 9181 | CA | PHE | G | 626 | −2.471 | 57.991 | 56.854 | 1.00 | 45.42 | G | C |
| ATOM | 9182 | CB | PHE | G | 626 | −2.529 | 56.991 | 55.690 | 1.00 | 43.74 | G | C |
| ATOM | 9183 | CG | PHE | G | 626 | −2.415 | 55.546 | 56.135 | 1.00 | 47.39 | G | C |
| ATOM | 9184 | CD1 | PHE | G | 626 | −1.213 | 55.050 | 56.682 | 1.00 | 45.44 | G | C |
| ATOM | 9185 | CD2 | PHE | G | 626 | −3.507 | 54.685 | 56.048 | 1.00 | 48.03 | G | C |
| ATOM | 9186 | CE1 | PHE | G | 626 | −1.099 | 53.708 | 57.142 | 1.00 | 44.18 | G | C |
| ATOM | 9187 | CE2 | PHE | G | 626 | −3.408 | 53.334 | 56.507 | 1.00 | 47.96 | G | C |
| ATOM | 9188 | CZ | PHE | G | 626 | −2.199 | 52.850 | 57.055 | 1.00 | 44.73 | G | C |
| ATOM | 9189 | C | PHE | G | 626 | −2.351 | 59.427 | 56.325 | 1.00 | 44.76 | G | C |
| ATOM | 9190 | O | PHE | G | 626 | −1.292 | 60.040 | 56.446 | 1.00 | 46.46 | G | O |
| ATOM | 9191 | N | LEU | G | 627 | −3.427 | 59.988 | 55.782 | 1.00 | 43.54 | G | N |
| ATOM | 9192 | CA | LEU | G | 627 | −3.345 | 61.326 | 55.177 | 1.00 | 39.06 | G | C |
| ATOM | 9193 | CB | LEU | G | 627 | −3.246 | 61.172 | 53.658 | 1.00 | 33.98 | G | C |
| ATOM | 9194 | CG | LEU | G | 627 | −2.041 | 61.739 | 52.929 | 1.00 | 32.99 | G | C |
| ATOM | 9195 | CD1 | LEU | G | 627 | −2.325 | 61.639 | 51.444 | 1.00 | 31.08 | G | C |
| ATOM | 9196 | CD2 | LEU | G | 627 | −1.763 | 63.167 | 53.346 | 1.00 | 31.77 | G | C |
| ATOM | 9197 | C | LEU | G | 627 | −4.476 | 62.303 | 55.465 | 1.00 | 36.78 | G | C |
| ATOM | 9198 | O | LEU | G | 627 | −5.641 | 61.929 | 55.479 | 1.00 | 36.97 | G | O |
| ATOM | 9199 | N | GLU | G | 628 | −4.115 | 63.567 | 55.653 | 1.00 | 35.83 | G | N |
| ATOM | 9200 | CA | GLU | G | 628 | −5.085 | 64.634 | 55.909 | 1.00 | 34.23 | G | C |
| ATOM | 9201 | CB | GLU | G | 628 | −4.338 | 65.881 | 56.374 | 1.00 | 35.69 | G | C |
| ATOM | 9202 | CG | GLU | G | 628 | −4.921 | 67.165 | 55.899 | 1.00 | 40.25 | G | C |
| ATOM | 9203 | CD | GLU | G | 628 | −4.061 | 68.321 | 56.295 | 1.00 | 45.16 | G | C |
| ATOM | 9204 | OE1 | GLU | G | 628 | −3.092 | 68.089 | 57.057 | 1.00 | 46.09 | G | O |
| ATOM | 9205 | OE2 | GLU | G | 628 | −4.351 | 69.451 | 55.845 | 1.00 | 48.50 | G | O |
| ATOM | 9206 | C | GLU | G | 628 | −5.871 | 64.902 | 54.606 | 1.00 | 31.44 | G | C |
| ATOM | 9207 | O | GLU | G | 628 | −5.273 | 65.096 | 53.541 | 1.00 | 28.75 | G | O |
| ATOM | 9208 | N | TYR | G | 629 | −7.201 | 64.940 | 54.702 | 1.00 | 26.45 | G | N |
| ATOM | 9209 | CA | TYR | G | 629 | −8.052 | 65.085 | 53.525 | 1.00 | 24.13 | G | C |
| ATOM | 9210 | CB | TYR | G | 629 | −9.461 | 65.551 | 53.898 | 1.00 | 21.67 | G | C |
| ATOM | 9211 | CG | TYR | G | 629 | −10.453 | 65.161 | 52.819 | 1.00 | 19.97 | G | C |
| ATOM | 9212 | CD1 | TYR | G | 629 | −10.606 | 65.938 | 51.671 | 1.00 | 21.45 | G | C |
| ATOM | 9213 | CE1 | TYR | G | 629 | −11.436 | 65.526 | 50.625 | 1.00 | 18.93 | G | C |
| ATOM | 9214 | CD2 | TYR | G | 629 | −11.164 | 63.965 | 52.895 | 1.00 | 20.27 | G | C |
| ATOM | 9215 | CE2 | TYR | G | 629 | −11.995 | 63.548 | 51.855 | 1.00 | 14.62 | G | C |
| ATOM | 9216 | CZ | TYR | G | 629 | −12.117 | 64.331 | 50.728 | 1.00 | 15.96 | G | C |
| ATOM | 9217 | OH | TYR | G | 629 | −12.898 | 63.917 | 49.685 | 1.00 | 16.02 | G | O |
| ATOM | 9218 | C | TYR | G | 629 | −7.569 | 65.915 | 52.350 | 1.00 | 23.55 | G | C |
| ATOM | 9219 | O | TYR | G | 629 | −7.413 | 65.396 | 51.259 | 1.00 | 24.31 | G | O |
| ATOM | 9220 | N | ALA | G | 630 | −7.352 | 67.200 | 52.563 | 1.00 | 23.92 | G | N |
| ATOM | 9221 | CA | ALA | G | 630 | −6.900 | 68.089 | 51.500 | 1.00 | 23.69 | G | C |
| ATOM | 9222 | CB | ALA | G | 630 | −6.799 | 69.519 | 52.049 | 1.00 | 24.43 | G | C |
| ATOM | 9223 | C | ALA | G | 630 | −5.570 | 67.691 | 50.840 | 1.00 | 24.80 | G | C |
| ATOM | 9224 | O | ALA | G | 630 | −5.268 | 68.140 | 49.738 | 1.00 | 24.81 | G | O |
| ATOM | 9225 | N | LYS | G | 631 | −4.775 | 66.861 | 51.507 | 1.00 | 23.06 | G | N |
| ATOM | 9226 | CA | LYS | G | 631 | −3.483 | 66.446 | 50.969 | 1.00 | 19.51 | G | C |
| ATOM | 9227 | CB | LYS | G | 631 | −2.487 | 66.239 | 52.114 | 1.00 | 24.24 | G | C |
| ATOM | 9228 | CG | LYS | G | 631 | −1.573 | 67.422 | 52.384 | 1.00 | 30.47 | G | C |
| ATOM | 9229 | CD | LYS | G | 631 | −2.249 | 68.466 | 53.251 | 1.00 | 36.62 | G | C |
| ATOM | 9230 | CE | LYS | G | 631 | −1.378 | 69.728 | 53.384 | 1.00 | 42.31 | G | C |
| ATOM | 9231 | NZ | LYS | G | 631 | −2.046 | 70.807 | 54.187 | 1.00 | 45.24 | G | N |
| ATOM | 9232 | C | LYS | G | 631 | −3.557 | 65.157 | 50.161 | 1.00 | 19.13 | G | C |
| ATOM | 9233 | O | LYS | G | 631 | −2.537 | 64.679 | 49.678 | 1.00 | 19.45 | G | O |
| ATOM | 9234 | N | ASN | G | 632 | −4.749 | 64.578 | 50.034 | 1.00 | 16.11 | G | N |
| ATOM | 9235 | CA | ASN | G | 632 | −4.915 | 63.326 | 49.287 | 1.00 | 16.42 | G | C |
| ATOM | 9236 | CB | ASN | G | 632 | −6.360 | 62.827 | 49.417 | 1.00 | 13.88 | G | C |
| ATOM | 9237 | CG | ASN | G | 632 | −6.491 | 61.341 | 49.135 | 1.00 | 18.16 | G | C |
| ATOM | 9238 | OD1 | ASN | G | 632 | −6.657 | 60.529 | 50.057 | 1.00 | 17.25 | G | O |
| ATOM | 9239 | ND2 | ASN | G | 632 | −6.408 | 60.971 | 47.855 | 1.00 | 14.48 | G | N |
| ATOM | 9240 | C | ASN | G | 632 | −4.566 | 63.503 | 47.796 | 1.00 | 14.87 | G | C |
| ATOM | 9241 | O | ASN | G | 632 | −5.020 | 64.451 | 47.170 | 1.00 | 13.37 | G | O |
| ATOM | 9242 | N | PRO | G | 633 | −3.767 | 62.581 | 47.219 | 1.00 | 16.14 | G | N |
| ATOM | 9243 | CD | PRO | G | 633 | −3.185 | 61.393 | 47.875 | 1.00 | 15.34 | G | C |
| ATOM | 9244 | CA | PRO | G | 633 | −3.378 | 62.662 | 45.801 | 1.00 | 17.16 | G | C |
| ATOM | 9245 | CB | PRO | G | 633 | −2.306 | 61.574 | 45.658 | 1.00 | 16.11 | G | C |
| ATOM | 9246 | CG | PRO | G | 633 | −2.676 | 60.571 | 46.708 | 1.00 | 14.60 | G | C |
| ATOM | 9247 | C | PRO | G | 633 | −4.550 | 62.441 | 44.824 | 1.00 | 17.13 | G | C |
| ATOM | 9248 | O | PRO | G | 633 | −4.376 | 62.530 | 43.615 | 1.00 | 16.68 | G | O |
| ATOM | 9249 | N | PHE | G | 634 | −5.740 | 62.160 | 45.353 | 1.00 | 15.87 | G | N |
| ATOM | 9250 | CA | PHE | G | 634 | −6.919 | 61.924 | 44.522 | 1.00 | 13.92 | G | C |
| ATOM | 9251 | CB | PHE | G | 634 | −8.178 | 61.873 | 45.400 | 1.00 | 11.03 | G | C |
| ATOM | 9252 | CG | PHE | G | 634 | −9.466 | 61.903 | 44.619 | 1.00 | 13.14 | G | C |
| ATOM | 9253 | CD1 | PHE | G | 634 | −10.181 | 63.080 | 44.475 | 1.00 | 13.25 | G | C |
| ATOM | 9254 | CD2 | PHE | G | 634 | −9.953 | 60.753 | 44.000 | 1.00 | 14.43 | G | C |
| ATOM | 9255 | CE1 | PHE | G | 634 | −11.359 | 63.118 | 43.723 | 1.00 | 11.82 | G | C |
| ATOM | 9256 | CE2 | PHE | G | 634 | −11.132 | 60.788 | 43.248 | 1.00 | 14.00 | G | C |
| ATOM | 9257 | CZ | PHE | G | 634 | −11.832 | 61.977 | 43.112 | 1.00 | 9.15 | G | C |
| ATOM | 9258 | C | PHE | G | 634 | −7.122 | 62.944 | 43.383 | 1.00 | 16.46 | G | C |
| ATOM | 9259 | O | PHE | G | 634 | −7.310 | 62.550 | 42.224 | 1.00 | 17.02 | G | O |
| ATOM | 9260 | N | LEU | G | 635 | −7.098 | 64.240 | 43.690 | 1.00 | 14.16 | G | N |
| ATOM | 9261 | CA | LEU | G | 635 | −7.317 | 65.238 | 42.647 | 1.00 | 12.30 | G | C |
| ATOM | 9262 | CB | LEU | G | 635 | −7.467 | 66.633 | 43.246 | 1.00 | 12.01 | G | C |
| ATOM | 9263 | CG | LEU | G | 635 | −7.730 | 67.780 | 42.260 | 1.00 | 11.21 | G | C |
| ATOM | 9264 | CD1 | LEU | G | 635 | −9.061 | 67.567 | 41.533 | 1.00 | 8.59 | G | C |
| ATOM | 9265 | CD2 | LEU | G | 635 | −7.734 | 69.097 | 43.002 | 1.00 | 9.35 | G | C |
| ATOM | 9266 | C | LEU | G | 635 | −6.186 | 65.253 | 41.627 | 1.00 | 13.61 | G | C |
| ATOM | 9267 | O | LEU | G | 635 | −6.423 | 65.348 | 40.420 | 1.00 | 15.09 | G | O |
| ATOM | 9268 | N | ASP | G | 636 | −4.957 | 65.175 | 42.112 | 1.00 | 10.60 | G | N |
| ATOM | 9269 | CA | ASP | G | 636 | −3.798 | 65.174 | 41.244 | 1.00 | 12.15 | G | C |
| ATOM | 9270 | CB | ASP | G | 636 | −2.534 | 65.055 | 42.073 | 1.00 | 11.18 | G | C |
| ATOM | 9271 | CG | ASP | G | 636 | −1.308 | 65.288 | 41.261 | 1.00 | 13.29 | G | C |
| ATOM | 9272 | OD1 | ASP | G | 636 | −1.279 | 66.287 | 40.519 | 1.00 | 18.09 | G | O |
| ATOM | 9273 | OD2 | ASP | G | 636 | −0.374 | 64.476 | 41.360 | 1.00 | 17.40 | G | O |
| ATOM | 9274 | C | ASP | G | 636 | −3.853 | 64.027 | 40.230 | 1.00 | 13.04 | G | C |
| ATOM | 9275 | O | ASP | G | 636 | −3.616 | 64.235 | 39.045 | 1.00 | 16.66 | G | O |
| ATOM | 9276 | N | PHE | G | 637 | −4.140 | 62.818 | 40.707 | 1.00 | 11.53 | G | N |
| ATOM | 9277 | CA | PHE | G | 637 | −4.240 | 61.641 | 39.861 | 1.00 | 10.15 | G | C |
| ATOM | 9278 | CB | PHE | G | 637 | −4.494 | 60.400 | 40.717 | 1.00 | 9.78 | G | C |
| ATOM | 9279 | CG | PHE | G | 637 | −3.303 | 59.967 | 41.548 | 1.00 | 13.34 | G | C |
| ATOM | 9280 | CD1 | PHE | G | 637 | −2.052 | 60.582 | 41.394 | 1.00 | 11.46 | G | C |
| ATOM | 9281 | CD2 | PHE | G | 637 | −3.423 | 58.910 | 42.464 | 1.00 | 14.09 | G | C |
| ATOM | 9282 | CE1 | PHE | G | 637 | −0.945 | 60.142 | 42.133 | 1.00 | 11.12 | G | C |
| ATOM | 9283 | CE2 | PHE | G | 637 | −2.317 | 58.465 | 43.207 | 1.00 | 9.04 | G | C |
| ATOM | 9284 | CZ | PHE | G | 637 | −1.080 | 59.079 | 43.038 | 1.00 | 10.31 | G | C |
| ATOM | 9285 | C | PHE | G | 637 | −5.375 | 61.803 | 38.849 | 1.00 | 11.08 | G | C |
| ATOM | 9286 | O | PHE | G | 637 | −5.233 | 61.457 | 37.679 | 1.00 | 10.36 | G | O |
| ATOM | 9287 | N | LEU | G | 638 | −6.500 | 62.338 | 39.303 | 1.00 | 8.75 | G | N |
| ATOM | 9288 | CA | LEU | G | 638 | −7.653 | 62.535 | 38.445 | 1.00 | 10.40 | G | C |
| ATOM | 9289 | CB | LEU | G | 638 | −8.828 | 63.055 | 39.264 | 1.00 | 11.65 | G | C |
| ATOM | 9290 | CG | LEU | G | 638 | −10.125 | 63.230 | 38.479 | 1.00 | 14.78 | G | C |
| ATOM | 9291 | CD1 | LEU | G | 638 | −10.708 | 61.855 | 38.178 | 1.00 | 19.88 | G | C |
| ATOM | 9292 | CD2 | LEU | G | 638 | −11.113 | 64.057 | 39.267 | 1.00 | 13.31 | G | C |
| ATOM | 9293 | C | LEU | G | 638 | −7.382 | 63.508 | 37.302 | 1.00 | 13.54 | G | C |
| ATOM | 9294 | O | LEU | G | 638 | −7.753 | 63.260 | 36.148 | 1.00 | 14.08 | G | O |
| ATOM | 9295 | N | GLN | G | 639 | −6.752 | 64.628 | 37.628 | 1.00 | 13.06 | G | N |
| ATOM | 9296 | CA | GLN | G | 639 | −6.437 | 65.639 | 36.635 | 1.00 | 13.02 | G | C |
| ATOM | 9297 | CB | GLN | G | 639 | −5.850 | 66.876 | 37.314 | 1.00 | 13.56 | G | C |
| ATOM | 9298 | CG | GLN | G | 639 | −6.842 | 67.637 | 38.184 | 1.00 | 14.34 | G | C |
| ATOM | 9299 | CD | GLN | G | 639 | −6.207 | 68.843 | 38.827 | 1.00 | 14.53 | G | C |
| ATOM | 9300 | OE1 | GLN | G | 639 | −5.036 | 68.813 | 39.184 | 1.00 | 18.23 | G | O |
| ATOM | 9301 | NE2 | GLN | G | 639 | −6.965 | 69.910 | 38.966 | 1.00 | 15.45 | G | N |
| ATOM | 9302 | C | GLN | G | 639 | −5.439 | 65.117 | 35.620 | 1.00 | 14.28 | G | C |
| ATOM | 9303 | O | GLN | G | 639 | −5.565 | 65.389 | 34.426 | 1.00 | 13.31 | G | O |
| ATOM | 9304 | N | LYS | G | 640 | −4.446 | 64.375 | 36.105 | 1.00 | 11.23 | G | N |
| ATOM | 9305 | CA | LYS | G | 640 | −3.406 | 63.838 | 35.243 | 1.00 | 11.14 | G | C |
| ATOM | 9306 | CB | LYS | G | 640 | −2.271 | 63.247 | 36.081 | 1.00 | 9.50 | G | C |
| ATOM | 9307 | CG | LYS | G | 640 | −1.509 | 64.268 | 36.904 | 1.00 | 5.76 | G | C |
| ATOM | 9308 | CD | LYS | G | 640 | −0.439 | 63.566 | 37.706 | 1.00 | 7.19 | G | C |
| ATOM | 9309 | CE | LYS | G | 640 | 0.536 | 64.546 | 38.330 | 1.00 | 6.12 | G | C |
| ATOM | 9310 | NZ | LYS | G | 640 | 1.376 | 63.816 | 39.315 | 1.00 | 9.01 | G | N |
| ATOM | 9311 | C | LYS | G | 640 | −3.937 | 62.783 | 34.276 | 1.00 | 10.42 | G | C |
| ATOM | 9312 | O | LYS | G | 640 | −3.298 | 62.494 | 33.270 | 1.00 | 10.15 | G | O |
| ATOM | 9313 | N | GLY | G | 641 | −5.091 | 62.202 | 34.596 | 1.00 | 10.82 | G | N |
| ATOM | 9314 | CA | GLY | G | 641 | −5.681 | 61.196 | 33.732 | 1.00 | 10.10 | G | C |
| ATOM | 9315 | C | GLY | G | 641 | −5.561 | 59.748 | 34.182 | 1.00 | 11.91 | G | C |
| ATOM | 9316 | O | GLY | G | 641 | −5.841 | 58.850 | 33.385 | 1.00 | 9.75 | G | O |
| ATOM | 9317 | N | LEU | G | 642 | −5.136 | 59.485 | 35.423 | 1.00 | 9.11 | G | N |
| ATOM | 9318 | CA | LEU | G | 642 | −5.060 | 58.085 | 35.862 | 1.00 | 9.30 | G | C |
| ATOM | 9319 | CB | LEU | G | 642 | −4.325 | 57.912 | 37.201 | 1.00 | 9.33 | G | C |
| ATOM | 9320 | CG | LEU | G | 642 | −2.881 | 58.354 | 37.542 | 1.00 | 11.64 | G | C |
| ATOM | 9321 | CD1 | LEU | G | 642 | −2.081 | 57.133 | 37.861 | 1.00 | 10.41 | G | C |
| ATOM | 9322 | CD2 | LEU | G | 642 | −2.222 | 59.179 | 36.467 | 1.00 | 8.13 | G | C |
| ATOM | 9323 | C | LEU | G | 642 | −6.506 | 57.630 | 36.006 | 1.00 | 8.32 | G | C |
| ATOM | 9324 | O | LEU | G | 642 | −7.403 | 58.444 | 36.234 | 1.00 | 7.29 | G | O |
| ATOM | 9325 | N | MET | G | 643 | −6.728 | 56.331 | 35.848 | 1.00 | 12.25 | G | N |
| ATOM | 9326 | CA | MET | G | 643 | −8.061 | 55.738 | 35.918 | 1.00 | 12.63 | G | C |
| ATOM | 9327 | CB | MET | G | 643 | −8.002 | 54.346 | 35.270 | 1.00 | 17.70 | G | C |
| ATOM | 9328 | CG | MET | G | 643 | −9.177 | 54.011 | 34.361 | 1.00 | 19.58 | G | C |
| ATOM | 9329 | SD | MET | G | 643 | −10.598 | 53.548 | 35.327 | 1.00 | 29.32 | G | S |
| ATOM | 9330 | CE | MET | G | 643 | −11.483 | 52.455 | 34.126 | 1.00 | 17.37 | G | C |
| ATOM | 9331 | C | MET | G | 643 | −8.534 | 55.655 | 37.378 | 1.00 | 11.67 | G | C |
| ATOM | 9332 | O | MET | G | 643 | −8.335 | 54.644 | 38.049 | 1.00 | 10.89 | G | O |
| ATOM | 9333 | N | ILE | G | 644 | −9.193 | 56.712 | 37.843 | 1.00 | 10.13 | G | N |
| ATOM | 9334 | CA | ILE | G | 644 | −9.628 | 56.812 | 39.241 | 1.00 | 13.64 | G | C |
| ATOM | 9335 | CB | ILE | G | 644 | −9.197 | 58.200 | 39.849 | 1.00 | 14.03 | G | C |
| ATOM | 9336 | CG2 | ILE | G | 644 | −9.589 | 58.278 | 41.275 | 1.00 | 13.33 | G | C |
| ATOM | 9337 | CG1 | ILE | G | 644 | −7.690 | 58.421 | 39.711 | 1.00 | 13.06 | G | C |
| ATOM | 9338 | CD1 | ILE | G | 644 | −6.864 | 57.343 | 40.316 | 1.00 | 12.09 | G | C |
| ATOM | 9339 | C | ILE | G | 644 | −11.122 | 56.677 | 39.535 | 1.00 | 12.31 | G | C |
| ATOM | 9340 | O | ILE | G | 644 | −11.949 | 57.187 | 38.788 | 1.00 | 12.25 | G | O |
| ATOM | 9341 | N | SER | G | 645 | −11.461 | 55.987 | 40.622 | 1.00 | 11.33 | G | N |
| ATOM | 9342 | CA | SER | G | 645 | −12.859 | 55.885 | 41.055 | 1.00 | 11.88 | G | C |
| ATOM | 9343 | CB | SER | G | 645 | −13.439 | 54.499 | 40.746 | 1.00 | 10.31 | G | C |
| ATOM | 9344 | OG | SER | G | 645 | −12.917 | 53.504 | 41.600 | 1.00 | 12.12 | G | O |
| ATOM | 9345 | C | SER | G | 645 | −12.897 | 56.169 | 42.582 | 1.00 | 13.09 | G | C |
| ATOM | 9346 | O | SER | G | 645 | −11.901 | 55.980 | 43.279 | 1.00 | 11.16 | G | O |
| ATOM | 9347 | N | LEU | G | 646 | −14.027 | 56.657 | 43.089 | 1.00 | 14.44 | G | N |
| ATOM | 9348 | CA | LEU | G | 646 | −14.168 | 56.936 | 44.514 | 1.00 | 11.49 | G | C |
| ATOM | 9349 | CB | LEU | G | 646 | −15.036 | 58.167 | 44.736 | 1.00 | 9.25 | G | C |
| ATOM | 9350 | CG | LEU | G | 646 | −14.301 | 59.505 | 44.640 | 1.00 | 9.94 | G | C |
| ATOM | 9351 | CD1 | LEU | G | 646 | −15.306 | 60.632 | 44.723 | 1.00 | 5.20 | G | C |
| ATOM | 9352 | CD2 | LEU | G | 646 | −13.266 | 59.624 | 45.761 | 1.00 | 5.42 | G | C |
| ATOM | 9353 | C | LEU | G | 646 | −14.818 | 55.739 | 45.184 | 1.00 | 14.01 | G | C |
| ATOM | 9354 | O | LEU | G | 646 | −15.730 | 55.102 | 44.623 | 1.00 | 11.29 | G | O |
| ATOM | 9355 | N | SER | G | 647 | −14.326 | 55.414 | 46.374 | 1.00 | 13.24 | G | N |
| ATOM | 9356 | CA | SER | G | 647 | −14.863 | 54.303 | 47.130 | 1.00 | 11.62 | G | C |
| ATOM | 9357 | CB | SER | G | 647 | −13.998 | 53.058 | 46.947 | 1.00 | 10.91 | G | C |
| ATOM | 9358 | OG | SER | G | 647 | −12.682 | 53.295 | 47.396 | 1.00 | 13.82 | G | O |
| ATOM | 9359 | C | SER | G | 647 | −14.978 | 54.679 | 48.607 | 1.00 | 13.93 | G | C |
| ATOM | 9360 | O | SER | G | 647 | −14.418 | 55.668 | 49.073 | 1.00 | 13.66 | G | O |
| ATOM | 9361 | N | THR | G | 648 | −15.688 | 53.836 | 49.331 | 1.00 | 10.73 | G | N |
| ATOM | 9362 | CA | THR | G | 648 | −16.010 | 54.015 | 50.731 | 1.00 | 11.49 | G | C |
| ATOM | 9363 | CB | THR | G | 648 | −17.491 | 53.559 | 50.850 | 1.00 | 12.19 | G | C |
| ATOM | 9364 | OG1 | THR | G | 648 | −18.292 | 54.635 | 51.318 | 1.00 | 25.38 | G | O |
| ATOM | 9365 | CG2 | THR | G | 648 | −17.648 | 52.353 | 51.660 | 1.00 | 8.34 | G | C |
| ATOM | 9366 | C | THR | G | 648 | −15.082 | 53.341 | 51.767 | 1.00 | 11.68 | G | C |
| ATOM | 9367 | O | THR | G | 648 | −14.731 | 53.954 | 52.774 | 1.00 | 10.99 | G | O |
| ATOM | 9368 | N | ASP | G | 649 | −14.681 | 52.093 | 51.509 | 1.00 | 12.57 | G | N |
| ATOM | 9369 | CA | ASP | G | 649 | −13.820 | 51.320 | 52.413 | 1.00 | 13.42 | G | C |
| ATOM | 9370 | CB | ASP | G | 649 | −12.635 | 52.176 | 52.912 | 1.00 | 11.06 | G | C |
| ATOM | 9371 | CG | ASP | G | 649 | −11.550 | 51.341 | 53.600 | 1.00 | 12.31 | G | C |
| ATOM | 9372 | OD1 | ASP | G | 649 | −11.696 | 50.099 | 53.658 | 1.00 | 16.26 | G | O |
| ATOM | 9373 | OD2 | ASP | G | 649 | −10.552 | 51.919 | 54.084 | 1.00 | 10.01 | G | O |
| ATOM | 9374 | C | ASP | G | 649 | −14.621 | 50.757 | 53.604 | 1.00 | 12.74 | G | C |
| ATOM | 9375 | O | ASP | G | 649 | −15.070 | 49.607 | 53.556 | 1.00 | 11.18 | G | O |
| ATOM | 9376 | N | ASP | G | 650 | −14.799 | 51.565 | 54.655 | 1.00 | 14.63 | G | N |
| ATOM | 9377 | CA | ASP | G | 650 | −15.553 | 51.155 | 55.858 | 1.00 | 15.87 | G | C |
| ATOM | 9378 | CB | ASP | G | 650 | −14.622 | 50.901 | 57.053 | 1.00 | 16.77 | G | C |
| ATOM | 9379 | CG | ASP | G | 650 | −13.774 | 49.658 | 56.887 | 1.00 | 24.73 | G | C |
| ATOM | 9380 | OD1 | ASP | G | 650 | −12.577 | 49.731 | 57.220 | 1.00 | 31.78 | G | O |
| ATOM | 9381 | OD2 | ASP | G | 650 | −14.283 | 48.603 | 56.432 | 1.00 | 28.94 | G | O |
| ATOM | 9382 | C | ASP | G | 650 | −16.563 | 52.221 | 56.285 | 1.00 | 16.83 | G | C |
| ATOM | 9383 | O | ASP | G | 650 | −16.265 | 53.048 | 57.151 | 1.00 | 19.00 | G | O |
| ATOM | 9384 | N | PRO | G | 651 | −17.766 | 52.223 | 55.685 | 1.00 | 15.93 | G | N |
| ATOM | 9385 | CD | PRO | G | 651 | −18.233 | 51.315 | 54.621 | 1.00 | 13.99 | G | C |
| ATOM | 9386 | CA | PRO | G | 651 | −18.786 | 53.212 | 56.043 | 1.00 | 14.14 | G | C |
| ATOM | 9387 | CB | PRO | G | 651 | −20.017 | 52.775 | 55.252 | 1.00 | 13.61 | G | C |
| ATOM | 9388 | CG | PRO | G | 651 | −19.495 | 51.976 | 54.140 | 1.00 | 13.18 | G | C |
| ATOM | 9389 | C | PRO | G | 651 | −19.086 | 53.276 | 57.533 | 1.00 | 14.43 | G | C |
| ATOM | 9390 | O | PRO | G | 651 | −19.300 | 54.358 | 58.069 | 1.00 | 12.65 | G | O |
| ATOM | 9391 | N | MET | G | 652 | −19.123 | 52.125 | 58.200 | 1.00 | 14.95 | G | N |
| ATOM | 9392 | CA | MET | G | 652 | −19.406 | 52.126 | 59.633 | 1.00 | 17.79 | G | C |
| ATOM | 9393 | CB | MET | G | 652 | −19.380 | 50.717 | 60.203 | 1.00 | 17.10 | G | C |
| ATOM | 9394 | CG | MET | G | 652 | −20.114 | 50.644 | 61.536 | 1.00 | 25.09 | G | C |
| ATOM | 9395 | SD | MET | G | 652 | −20.157 | 48.994 | 62.172 | 1.00 | 33.91 | G | S |
| ATOM | 9396 | CE | MET | G | 652 | −18.462 | 48.754 | 62.531 | 1.00 | 23.43 | G | C |
| ATOM | 9397 | C | MET | G | 652 | −18.440 | 52.998 | 60.425 | 1.00 | 16.41 | G | C |
| ATOM | 9398 | O | MET | G | 652 | −18.855 | 53.733 | 61.317 | 1.00 | 18.38 | G | O |
| ATOM | 9399 | N | GLN | G | 653 | −17.157 | 52.914 | 60.090 | 1.00 | 15.66 | G | N |
| ATOM | 9400 | CA | GLN | G | 653 | −16.118 | 53.698 | 60.754 | 1.00 | 16.95 | G | C |
| ATOM | 9401 | CB | GLN | G | 653 | −14.737 | 53.074 | 60.525 | 1.00 | 17.99 | G | C |
| ATOM | 9402 | CG | GLN | G | 653 | −14.313 | 52.049 | 61.530 | 1.00 | 26.39 | G | C |
| ATOM | 9403 | CD | GLN | G | 653 | −15.182 | 50.801 | 61.491 | 1.00 | 35.17 | G | C |
| ATOM | 9404 | OE1 | GLN | G | 653 | −15.912 | 50.508 | 62.447 | 1.00 | 36.99 | G | O |
| ATOM | 9405 | NE2 | GLN | G | 653 | −15.110 | 50.056 | 60.383 | 1.00 | 37.57 | G | N |
| ATOM | 9406 | C | GLN | G | 653 | −16.024 | 55.155 | 60.295 | 1.00 | 17.88 | G | C |
| ATOM | 9407 | O | GLN | G | 653 | −15.730 | 56.030 | 61.115 | 1.00 | 14.38 | G | O |
| ATOM | 9408 | N | PHE | G | 654 | −16.273 | 55.427 | 59.005 | 1.00 | 15.79 | G | N |
| ATOM | 9409 | CA | PHE | G | 654 | −16.087 | 56.789 | 58.491 | 1.00 | 13.94 | G | C |
| ATOM | 9410 | CB | PHE | G | 654 | −15.055 | 56.780 | 57.351 | 1.00 | 15.50 | G | C |
| ATOM | 9411 | CG | PHE | G | 654 | −13.885 | 55.858 | 57.583 | 1.00 | 15.25 | G | C |
| ATOM | 9412 | CD1 | PHE | G | 654 | −13.706 | 54.733 | 56.784 | 1.00 | 11.90 | G | C |
| ATOM | 9413 | CD2 | PHE | G | 654 | −12.952 | 56.126 | 58.584 | 1.00 | 13.46 | G | C |
| ATOM | 9414 | CE1 | PHE | G | 654 | −12.622 | 53.892 | 56.973 | 1.00 | 15.61 | G | C |
| ATOM | 9415 | CE2 | PHE | G | 654 | −11.851 | 55.276 | 58.783 | 1.00 | 13.80 | G | C |
| ATOM | 9416 | CZ | PHE | G | 654 | −11.690 | 54.161 | 57.973 | 1.00 | 12.89 | G | C |
| ATOM | 9417 | C | PHE | G | 654 | −17.246 | 57.636 | 58.014 | 1.00 | 14.91 | G | C |
| ATOM | 9418 | O | PHE | G | 654 | −17.101 | 58.852 | 57.871 | 1.00 | 17.72 | G | O |
| ATOM | 9419 | N | HIS | G | 655 | −18.397 | 57.036 | 57.761 | 1.00 | 15.73 | G | N |
| ATOM | 9420 | CA | HIS | G | 655 | −19.500 | 57.824 | 57.224 | 1.00 | 16.43 | G | C |
| ATOM | 9421 | CB | HIS | G | 655 | −19.973 | 57.177 | 55.910 | 1.00 | 13.08 | G | C |
| ATOM | 9422 | CG | HIS | G | 655 | −18.861 | 56.979 | 54.929 | 1.00 | 11.87 | G | C |
| ATOM | 9423 | CD2 | HIS | G | 655 | −17.856 | 56.070 | 54.895 | 1.00 | 9.81 | G | C |
| ATOM | 9424 | ND1 | HIS | G | 655 | −18.611 | 57.860 | 53.899 | 1.00 | 15.48 | G | N |
| ATOM | 9425 | CE1 | HIS | G | 655 | −17.500 | 57.507 | 53.276 | 1.00 | 11.56 | G | C |
| ATOM | 9426 | NE2 | HIS | G | 655 | −17.023 | 56.424 | 53.861 | 1.00 | 10.60 | G | N |
| ATOM | 9427 | C | HIS | G | 655 | −20.651 | 58.069 | 58.177 | 1.00 | 17.98 | G | C |
| ATOM | 9428 | O | HIS | G | 655 | −20.828 | 57.345 | 59.160 | 1.00 | 19.80 | G | O |
| ATOM | 9429 | N | PHE | G | 656 | −21.436 | 59.098 | 57.875 | 1.00 | 17.93 | G | N |
| ATOM | 9430 | CA | PHE | G | 656 | −22.542 | 59.477 | 58.730 | 1.00 | 19.56 | G | C |
| ATOM | 9431 | CB | PHE | G | 656 | −22.459 | 60.967 | 59.037 | 1.00 | 18.28 | G | C |
| ATOM | 9432 | CG | PHE | G | 656 | −21.207 | 61.371 | 59.774 | 1.00 | 22.19 | G | C |
| ATOM | 9433 | CD1 | PHE | G | 656 | −20.359 | 62.337 | 59.241 | 1.00 | 22.37 | G | C |
| ATOM | 9434 | CD2 | PHE | G | 656 | −20.895 | 60.817 | 61.017 | 1.00 | 22.60 | G | C |
| ATOM | 9435 | CE1 | PHE | G | 656 | −19.224 | 62.753 | 59.927 | 1.00 | 22.22 | G | C |
| ATOM | 9436 | CE2 | PHE | G | 656 | −19.759 | 61.230 | 61.713 | 1.00 | 23.61 | G | C |
| ATOM | 9437 | CZ | PHE | G | 656 | −18.924 | 62.201 | 61.166 | 1.00 | 23.10 | G | C |
| ATOM | 9438 | C | PHE | G | 656 | −23.937 | 59.176 | 58.236 | 1.00 | 21.93 | G | C |
| ATOM | 9439 | O | PHE | G | 656 | −24.881 | 59.208 | 59.028 | 1.00 | 26.22 | G | O |
| ATOM | 9440 | N | THR | G | 657 | −24.090 | 58.863 | 56.953 | 1.00 | 19.76 | G | N |
| ATOM | 9441 | CA | THR | G | 657 | −25.425 | 58.632 | 56.411 | 1.00 | 18.15 | G | C |
| ATOM | 9442 | CB | THR | G | 657 | −25.733 | 59.680 | 55.327 | 1.00 | 21.16 | G | C |
| ATOM | 9443 | OG1 | THR | G | 657 | −25.126 | 59.269 | 54.093 | 1.00 | 23.15 | G | O |
| ATOM | 9444 | CG2 | THR | G | 657 | −25.154 | 61.046 | 55.714 | 1.00 | 16.01 | G | C |
| ATOM | 9445 | C | THR | G | 657 | −25.654 | 57.254 | 55.816 | 1.00 | 19.51 | G | C |
| ATOM | 9446 | O | THR | G | 657 | −24.734 | 56.448 | 55.723 | 1.00 | 18.46 | G | O |
| ATOM | 9447 | N | LYS | G | 658 | −26.890 | 56.999 | 55.392 | 1.00 | 20.43 | G | N |
| ATOM | 9448 | CA | LYS | G | 658 | −27.249 | 55.712 | 54.784 | 1.00 | 24.26 | G | C |
| ATOM | 9449 | CB | LYS | G | 658 | −28.766 | 55.483 | 54.816 | 1.00 | 30.48 | G | C |
| ATOM | 9450 | CG | LYS | G | 658 | −29.480 | 56.015 | 56.069 | 1.00 | 41.64 | G | C |
| ATOM | 9451 | CD | LYS | G | 658 | −29.794 | 54.889 | 57.101 | 1.00 | 46.20 | G | C |
| ATOM | 9452 | CE | LYS | G | 658 | −29.483 | 55.310 | 58.553 | 1.00 | 44.06 | G | C |
| ATOM | 9453 | NZ | LYS | G | 658 | −28.301 | 54.597 | 59.098 | 1.00 | 42.87 | G | N |
| ATOM | 9454 | C | LYS | G | 658 | −26.782 | 55.648 | 53.331 | 1.00 | 21.31 | G | C |
| ATOM | 9455 | O | LYS | G | 658 | −26.976 | 54.638 | 52.661 | 1.00 | 20.44 | G | O |
| ATOM | 9456 | N | GLU | G | 659 | −26.172 | 56.731 | 52.859 | 1.00 | 21.03 | G | N |
| ATOM | 9457 | CA | GLU | G | 659 | −25.656 | 56.820 | 51.491 | 1.00 | 20.05 | G | C |
| ATOM | 9458 | CB | GLU | G | 659 | −26.455 | 57.854 | 50.712 | 1.00 | 21.73 | G | C |
| ATOM | 9459 | CG | GLU | G | 659 | −27.890 | 57.445 | 50.513 | 1.00 | 27.59 | G | C |
| ATOM | 9460 | CD | GLU | G | 659 | −28.569 | 58.233 | 49.410 | 1.00 | 34.78 | G | C |
| ATOM | 9461 | OE1 | GLU | G | 659 | −28.529 | 57.769 | 48.252 | 1.00 | 38.79 | G | O |
| ATOM | 9462 | OE2 | GLU | G | 659 | −29.135 | 59.315 | 49.696 | 1.00 | 37.62 | G | O |
| ATOM | 9463 | C | GLU | G | 659 | −24.198 | 57.231 | 51.536 | 1.00 | 15.58 | G | C |
| ATOM | 9464 | O | GLU | G | 659 | −23.845 | 58.326 | 51.116 | 1.00 | 16.82 | G | O |
| ATOM | 9465 | N | PRO | G | 660 | −23.325 | 56.342 | 52.032 | 1.00 | 16.43 | G | N |
| ATOM | 9466 | CD | PRO | G | 660 | −23.651 | 54.986 | 52.512 | 1.00 | 12.54 | G | C |
| ATOM | 9467 | CA | PRO | G | 660 | −21.892 | 56.637 | 52.140 | 1.00 | 14.03 | G | C |
| ATOM | 9468 | CB | PRO | G | 660 | −21.312 | 55.392 | 52.825 | 1.00 | 12.86 | G | C |
| ATOM | 9469 | CG | PRO | G | 660 | −22.322 | 54.315 | 52.565 | 1.00 | 12.60 | G | C |
| ATOM | 9470 | C | PRO | G | 660 | −21.164 | 56.990 | 50.846 | 1.00 | 12.74 | G | C |
| ATOM | 9471 | O | PRO | G | 660 | −20.293 | 57.871 | 50.848 | 1.00 | 14.91 | G | O |
| ATOM | 9472 | N | LEU | G | 661 | −21.497 | 56.315 | 49.750 | 1.00 | 12.64 | G | N |
| ATOM | 9473 | CA | LEU | G | 661 | −20.846 | 56.598 | 48.474 | 1.00 | 9.88 | G | C |
| ATOM | 9474 | CB | LEU | G | 661 | −21.328 | 55.629 | 47.395 | 1.00 | 10.90 | G | C |
| ATOM | 9475 | CG | LEU | G | 661 | −20.349 | 55.002 | 46.364 | 1.00 | 12.43 | G | C |
| ATOM | 9476 | CD1 | LEU | G | 661 | −21.004 | 55.000 | 44.984 | 1.00 | 7.02 | G | C |
| ATOM | 9477 | CD2 | LEU | G | 661 | −18.999 | 55.685 | 46.343 | 1.00 | 5.34 | G | C |
| ATOM | 9478 | C | LEU | G | 661 | −21.170 | 58.035 | 48.066 | 1.00 | 9.72 | G | C |
| ATOM | 9479 | O | LEU | G | 661 | −20.275 | 58.793 | 47.701 | 1.00 | 8.15 | G | O |
| ATOM | 9480 | N | MET | G | 662 | −22.449 | 58.414 | 48.128 | 1.00 | 10.04 | G | N |
| ATOM | 9481 | CA | MET | G | 662 | −22.832 | 59.779 | 47.768 | 1.00 | 12.68 | G | C |
| ATOM | 9482 | CB | MET | G | 662 | −24.334 | 59.966 | 47.913 | 1.00 | 13.50 | G | C |
| ATOM | 9483 | CG | MET | G | 662 | −25.141 | 59.187 | 46.897 | 1.00 | 16.64 | G | C |
| ATOM | 9484 | SD | MET | G | 662 | −24.643 | 59.545 | 45.183 | 1.00 | 24.96 | G | S |
| ATOM | 9485 | CE | MET | G | 662 | −25.645 | 60.952 | 44.789 | 1.00 | 17.26 | G | C |
| ATOM | 9486 | C | MET | G | 662 | −22.081 | 60.764 | 48.670 | 1.00 | 15.38 | G | C |
| ATOM | 9487 | O | MET | G | 662 | −21.711 | 61.865 | 48.242 | 1.00 | 14.98 | G | O |
| ATOM | 9488 | N | GLU | G | 663 | −21.850 | 60.349 | 49.914 | 1.00 | 14.35 | G | N |
| ATOM | 9489 | CA | GLU | G | 663 | −21.108 | 61.145 | 50.890 | 1.00 | 14.53 | G | C |
| ATOM | 9490 | CB | GLU | G | 663 | −21.112 | 60.423 | 52.249 | 1.00 | 17.65 | G | C |
| ATOM | 9491 | CG | GLU | G | 663 | −21.390 | 61.300 | 53.443 | 1.00 | 21.09 | G | C |
| ATOM | 9492 | CD | GLU | G | 663 | −21.373 | 60.533 | 54.760 | 1.00 | 19.99 | G | C |
| ATOM | 9493 | OE1 | GLU | G | 663 | −22.173 | 59.573 | 54.892 | 1.00 | 17.58 | G | O |
| ATOM | 9494 | OE2 | GLU | G | 663 | −20.560 | 60.911 | 55.641 | 1.00 | 20.30 | G | O |
| ATOM | 9495 | C | GLU | G | 663 | −19.653 | 61.361 | 50.411 | 1.00 | 10.61 | G | C |
| ATOM | 9496 | O | GLU | G | 663 | −19.162 | 62.495 | 50.427 | 1.00 | 7.61 | G | O |
| ATOM | 9497 | N | GLU | G | 664 | −18.967 | 60.279 | 50.013 | 1.00 | 10.03 | G | N |
| ATOM | 9498 | CA | GLU | G | 664 | −17.585 | 60.379 | 49.509 | 1.00 | 12.75 | G | C |
| ATOM | 9499 | CB | GLU | G | 664 | −17.065 | 59.051 | 48.973 | 1.00 | 14.98 | G | C |
| ATOM | 9500 | CG | GLU | G | 664 | −16.585 | 58.087 | 50.014 | 1.00 | 24.25 | G | C |
| ATOM | 9501 | CD | GLU | G | 664 | −15.229 | 58.403 | 50.604 | 1.00 | 19.66 | G | C |
| ATOM | 9502 | OE1 | GLU | G | 664 | −14.453 | 59.244 | 50.082 | 1.00 | 17.18 | G | O |
| ATOM | 9503 | OE2 | GLU | G | 664 | −14.948 | 57.767 | 51.631 | 1.00 | 22.91 | G | O |
| ATOM | 9504 | C | GLU | G | 664 | −17.532 | 61.350 | 48.351 | 1.00 | 11.43 | G | C |
| ATOM | 9505 | O | GLU | G | 664 | −16.645 | 62.194 | 48.279 | 1.00 | 12.10 | G | O |
| ATOM | 9506 | N | TYR | G | 665 | −18.486 | 61.202 | 47.435 | 1.00 | 9.40 | G | N |
| ATOM | 9507 | CA | TYR | G | 665 | −18.565 | 62.071 | 46.269 | 1.00 | 11.94 | G | C |
| ATOM | 9508 | CB | TYR | G | 665 | −19.682 | 61.614 | 45.323 | 1.00 | 12.14 | G | C |
| ATOM | 9509 | CG | TYR | G | 665 | −19.265 | 60.560 | 44.315 | 1.00 | 14.97 | G | C |
| ATOM | 9510 | CD1 | TYR | G | 665 | −19.224 | 59.208 | 44.666 | 1.00 | 10.87 | G | C |
| ATOM | 9511 | CE1 | TYR | G | 665 | −18.853 | 58.228 | 43.728 | 1.00 | 14.35 | G | C |
| ATOM | 9512 | CD2 | TYR | G | 665 | −18.927 | 60.915 | 42.996 | 1.00 | 14.18 | G | C |
| ATOM | 9513 | CE2 | TYR | G | 665 | −18.556 | 59.942 | 42.047 | 1.00 | 11.96 | G | C |
| ATOM | 9514 | CZ | TYR | G | 665 | −18.520 | 58.603 | 42.425 | 1.00 | 15.18 | G | C |
| ATOM | 9515 | OH | TYR | G | 665 | −18.126 | 57.643 | 41.514 | 1.00 | 15.96 | G | O |
| ATOM | 9516 | C | TYR | G | 665 | −18.813 | 63.521 | 46.655 | 1.00 | 10.85 | G | C |
| ATOM | 9517 | O | TYR | G | 665 | −18.187 | 64.422 | 46.106 | 1.00 | 14.01 | G | O |
| ATOM | 9518 | N | ALA | G | 666 | −19.727 | 63.755 | 47.592 | 1.00 | 8.78 | G | N |
| ATOM | 9519 | CA | ALA | G | 666 | −20.032 | 65.125 | 48.009 | 1.00 | 8.28 | G | C |
| ATOM | 9520 | CB | ALA | G | 666 | −21.181 | 65.117 | 48.993 | 1.00 | 5.73 | G | C |
| ATOM | 9521 | C | ALA | G | 666 | −18.840 | 65.880 | 48.599 | 1.00 | 9.48 | G | C |
| ATOM | 9522 | O | ALA | G | 666 | −18.525 | 66.993 | 48.174 | 1.00 | 9.08 | G | O |
| ATOM | 9523 | N | ILE | G | 667 | −18.165 | 65.290 | 49.577 | 1.00 | 12.97 | G | N |
| ATOM | 9524 | CA | ILE | G | 667 | −17.039 | 65.998 | 50.161 | 1.00 | 13.45 | G | C |
| ATOM | 9525 | CB | ILE | G | 667 | −16.517 | 65.326 | 51.491 | 1.00 | 12.68 | G | C |
| ATOM | 9526 | CG2 | ILE | G | 667 | −15.983 | 63.921 | 51.242 | 1.00 | 12.88 | G | C |
| ATOM | 9527 | CG1 | ILE | G | 667 | −15.417 | 66.196 | 52.089 | 1.00 | 11.91 | G | C |
| ATOM | 9528 | CD1 | ILE | G | 667 | −14.723 | 65.555 | 53.233 | 1.00 | 23.87 | G | C |
| ATOM | 9529 | C | ILE | G | 667 | −15.910 | 66.146 | 49.152 | 1.00 | 12.54 | G | C |
| ATOM | 9530 | O | ILE | G | 667 | −15.223 | 67.167 | 49.143 | 1.00 | 11.79 | G | O |
| ATOM | 9531 | N | ALA | G | 668 | −15.721 | 65.152 | 48.291 | 1.00 | 11.86 | G | N |
| ATOM | 9532 | CA | ALA | G | 668 | −14.650 | 65.254 | 47.301 | 1.00 | 11.61 | G | C |
| ATOM | 9533 | CB | ALA | G | 668 | −14.552 | 63.964 | 46.492 | 1.00 | 8.54 | G | C |
| ATOM | 9534 | C | ALA | G | 668 | −14.941 | 66.439 | 46.389 | 1.00 | 10.96 | G | C |
| ATOM | 9535 | O | ALA | G | 668 | −14.066 | 67.237 | 46.073 | 1.00 | 11.27 | G | O |
| ATOM | 9536 | N | ALA | G | 669 | −16.193 | 66.562 | 45.979 | 1.00 | 12.41 | G | N |
| ATOM | 9537 | CA | ALA | G | 669 | −16.590 | 67.651 | 45.101 | 1.00 | 12.72 | G | C |
| ATOM | 9538 | CB | ALA | G | 669 | −18.038 | 67.487 | 44.684 | 1.00 | 9.38 | G | C |
| ATOM | 9539 | C | ALA | G | 669 | −16.403 | 68.980 | 45.804 | 1.00 | 14.80 | G | C |
| ATOM | 9540 | O | ALA | G | 669 | −15.900 | 69.940 | 45.213 | 1.00 | 12.56 | G | O |
| ATOM | 9541 | N | GLN | G | 670 | −16.812 | 69.029 | 47.072 | 1.00 | 18.25 | G | N |
| ATOM | 9542 | CA | GLN | G | 670 | −16.704 | 70.243 | 47.878 | 1.00 | 17.41 | G | C |
| ATOM | 9543 | CB | GLN | G | 670 | −17.377 | 70.059 | 49.251 | 1.00 | 20.58 | G | C |
| ATOM | 9544 | CG | GLN | G | 670 | −18.786 | 69.489 | 49.241 | 1.00 | 20.46 | G | C |
| ATOM | 9545 | CD | GLN | G | 670 | −19.839 | 70.560 | 49.171 | 1.00 | 25.48 | G | C |
| ATOM | 9546 | OE1 | GLN | G | 670 | −19.590 | 71.650 | 48.655 | 1.00 | 29.78 | G | O |
| ATOM | 9547 | NE2 | GLN | G | 670 | −21.033 | 70.263 | 49.685 | 1.00 | 24.40 | G | N |
| ATOM | 9548 | C | GLN | G | 670 | −15.266 | 70.719 | 48.105 | 1.00 | 17.05 | G | C |
| ATOM | 9549 | O | GLN | G | 670 | −14.945 | 71.872 | 47.793 | 1.00 | 16.73 | G | O |
| ATOM | 9550 | N | VAL | G | 671 | −14.394 | 69.863 | 48.639 | 1.00 | 14.66 | G | N |
| ATOM | 9551 | CA | VAL | G | 671 | −13.043 | 70.334 | 48.898 | 1.00 | 15.08 | G | C |
| ATOM | 9552 | CB | VAL | G | 671 | −12.407 | 69.642 | 50.187 | 1.00 | 15.36 | G | C |
| ATOM | 9553 | CG1 | VAL | G | 671 | −13.341 | 68.634 | 50.757 | 1.00 | 15.82 | G | C |
| ATOM | 9554 | CG2 | VAL | G | 671 | −11.047 | 69.054 | 49.886 | 1.00 | 12.95 | G | C |
| ATOM | 9555 | C | VAL | G | 671 | −12.097 | 70.284 | 47.706 | 1.00 | 14.79 | G | C |
| ATOM | 9556 | O | VAL | G | 671 | −11.206 | 71.113 | 47.610 | 1.00 | 15.29 | G | O |
| ATOM | 9557 | N | PHE | G | 672 | −12.287 | 69.346 | 46.785 | 1.00 | 15.26 | G | N |
| ATOM | 9558 | CA | PHE | G | 672 | −11.403 | 69.289 | 45.620 | 1.00 | 15.69 | G | C |
| ATOM | 9559 | CB | PHE | G | 672 | −11.214 | 67.852 | 45.154 | 1.00 | 12.62 | G | C |
| ATOM | 9560 | CG | PHE | G | 672 | −10.396 | 67.024 | 46.102 | 1.00 | 14.73 | G | C |
| ATOM | 9561 | CD1 | PHE | G | 672 | −9.134 | 67.450 | 46.507 | 1.00 | 18.16 | G | C |
| ATOM | 9562 | CD2 | PHE | G | 672 | −10.894 | 65.845 | 46.621 | 1.00 | 13.21 | G | C |
| ATOM | 9563 | CE1 | PHE | G | 672 | −8.394 | 66.706 | 47.417 | 1.00 | 18.63 | G | C |
| ATOM | 9564 | CE2 | PHE | G | 672 | −10.158 | 65.100 | 47.529 | 1.00 | 15.29 | G | C |
| ATOM | 9565 | CZ | PHE | G | 672 | −8.914 | 65.525 | 47.928 | 1.00 | 15.33 | G | C |
| ATOM | 9566 | C | PHE | G | 672 | −11.958 | 70.152 | 44.491 | 1.00 | 19.33 | G | C |
| ATOM | 9567 | O | PHE | G | 672 | −11.331 | 70.306 | 43.455 | 1.00 | 20.30 | G | O |
| ATOM | 9568 | N | LYS | G | 673 | −13.143 | 70.715 | 44.709 | 1.00 | 20.20 | G | N |
| ATOM | 9569 | CA | LYS | G | 673 | −13.793 | 71.608 | 43.747 | 1.00 | 20.63 | G | C |
| ATOM | 9570 | CB | LYS | G | 673 | −13.006 | 72.929 | 43.648 | 1.00 | 21.44 | G | C |
| ATOM | 9571 | CG | LYS | G | 673 | −13.307 | 73.895 | 44.795 | 1.00 | 25.50 | G | C |
| ATOM | 9572 | CD | LYS | G | 673 | −12.208 | 74.923 | 44.979 | 1.00 | 32.27 | G | C |
| ATOM | 9573 | CE | LYS | G | 673 | −11.072 | 74.382 | 45.845 | 1.00 | 37.83 | G | C |
| ATOM | 9574 | NZ | LYS | G | 673 | −10.134 | 75.454 | 46.339 | 1.00 | 38.14 | G | N |
| ATOM | 9575 | C | LYS | G | 673 | −13.964 | 70.981 | 42.366 | 1.00 | 19.86 | G | C |
| ATOM | 9576 | O | LYS | G | 673 | −13.559 | 71.547 | 41.347 | 1.00 | 19.61 | G | O |
| ATOM | 9577 | N | LEU | G | 674 | −14.586 | 69.812 | 42.354 | 1.00 | 16.94 | G | N |
| ATOM | 9578 | CA | LEU | G | 674 | −14.840 | 69.053 | 41.138 | 1.00 | 16.44 | G | C |
| ATOM | 9579 | CB | LEU | G | 674 | −15.128 | 67.593 | 41.505 | 1.00 | 14.60 | G | C |
| ATOM | 9580 | CG | LEU | G | 674 | −14.017 | 66.544 | 41.613 | 1.00 | 16.69 | G | C |
| ATOM | 9581 | CD1 | LEU | G | 674 | −12.682 | 67.191 | 41.798 | 1.00 | 14.02 | G | C |
| ATOM | 9582 | CD2 | LEU | G | 674 | −14.340 | 65.601 | 42.757 | 1.00 | 13.29 | G | C |
| ATOM | 9583 | C | LEU | G | 674 | −16.050 | 69.609 | 40.369 | 1.00 | 16.11 | G | C |
| ATOM | 9584 | O | LEU | G | 674 | −17.032 | 70.029 | 40.972 | 1.00 | 12.31 | G | O |
| ATOM | 9585 | N | SER | G | 675 | −15.983 | 69.604 | 39.035 | 1.00 | 15.45 | G | N |
| ATOM | 9586 | CA | SER | G | 675 | −17.110 | 70.068 | 38.222 | 1.00 | 13.75 | G | C |
| ATOM | 9587 | CB | SER | G | 675 | −16.645 | 70.450 | 36.815 | 1.00 | 15.03 | G | C |
| ATOM | 9588 | OG | SER | G | 675 | −16.222 | 69.293 | 36.110 | 1.00 | 19.00 | G | O |
| ATOM | 9589 | C | SER | G | 675 | −18.055 | 68.884 | 38.122 | 1.00 | 12.58 | G | C |
| ATOM | 9590 | O | SER | G | 675 | −17.693 | 67.761 | 38.502 | 1.00 | 13.82 | G | O |
| ATOM | 9591 | N | THR | G | 676 | −19.261 | 69.096 | 37.615 | 1.00 | 12.25 | G | N |
| ATOM | 9592 | CA | THR | G | 676 | −20.165 | 67.957 | 37.512 | 1.00 | 14.41 | G | C |
| ATOM | 9593 | CB | THR | G | 676 | −21.637 | 68.410 | 37.268 | 1.00 | 16.34 | G | C |
| ATOM | 9594 | OG1 | THR | G | 676 | −22.303 | 67.475 | 36.405 | 1.00 | 24.71 | G | O |
| ATOM | 9595 | CG2 | THR | G | 676 | −21.681 | 69.768 | 36.673 | 1.00 | 21.37 | G | C |
| ATOM | 9596 | C | THR | G | 676 | −19.655 | 66.977 | 36.439 | 1.00 | 13.09 | G | C |
| ATOM | 9597 | O | THR | G | 676 | −19.887 | 65.764 | 36.524 | 1.00 | 12.74 | G | O |
| ATOM | 9598 | N | CYS | G | 677 | −18.912 | 67.497 | 35.462 | 1.00 | 11.73 | G | N |
| ATOM | 9599 | CA | CYS | G | 677 | −18.337 | 66.647 | 34.435 | 1.00 | 9.64 | G | C |
| ATOM | 9600 | CB | CYS | G | 677 | −17.733 | 67.486 | 33.302 | 1.00 | 9.18 | G | C |
| ATOM | 9601 | SG | CYS | G | 677 | −17.081 | 66.466 | 31.911 | 1.00 | 11.39 | G | S |
| ATOM | 9602 | C | CYS | G | 677 | −17.258 | 65.786 | 35.093 | 1.00 | 10.69 | G | C |
| ATOM | 9603 | O | CYS | G | 677 | −17.134 | 64.600 | 34.783 | 1.00 | 11.71 | G | O |
| ATOM | 9604 | N | ASP | G | 678 | −16.484 | 66.375 | 36.006 | 1.00 | 10.87 | G | N |
| ATOM | 9605 | CA | ASP | G | 678 | −15.437 | 65.639 | 36.720 | 1.00 | 9.67 | G | C |
| ATOM | 9606 | CB | ASP | G | 678 | −14.742 | 66.543 | 37.740 | 1.00 | 11.56 | G | C |
| ATOM | 9607 | CG | ASP | G | 678 | −13.883 | 67.618 | 37.097 | 1.00 | 16.64 | G | C |
| ATOM | 9608 | OD1 | ASP | G | 678 | −13.389 | 67.407 | 35.964 | 1.00 | 20.20 | G | O |
| ATOM | 9609 | OD2 | ASP | G | 678 | −13.689 | 68.678 | 37.730 | 1.00 | 13.25 | G | O |
| ATOM | 9610 | C | ASP | G | 678 | −16.071 | 64.470 | 37.481 | 1.00 | 11.75 | G | C |
| ATOM | 9611 | O | ASP | G | 678 | −15.595 | 63.337 | 37.432 | 1.00 | 13.24 | G | O |
| ATOM | 9612 | N | MET | G | 679 | −17.155 | 64.761 | 38.187 | 1.00 | 12.30 | G | N |
| ATOM | 9613 | CA | MET | G | 679 | −17.859 | 63.760 | 38.971 | 1.00 | 14.98 | G | C |
| ATOM | 9614 | CB | MET | G | 679 | −18.963 | 64.440 | 39.783 | 1.00 | 17.55 | G | C |
| ATOM | 9615 | CG | MET | G | 679 | −18.478 | 65.496 | 40.779 | 1.00 | 22.48 | G | C |
| ATOM | 9616 | SD | MET | G | 679 | −19.886 | 66.005 | 41.818 | 1.00 | 36.17 | G | S |
| ATOM | 9617 | CE | MET | G | 679 | −20.248 | 67.651 | 41.150 | 1.00 | 32.88 | G | C |
| ATOM | 9618 | C | MET | G | 679 | −18.467 | 62.621 | 38.135 | 1.00 | 14.61 | G | C |
| ATOM | 9619 | O | MET | G | 679 | −18.403 | 61.453 | 38.519 | 1.00 | 14.94 | G | O |
| ATOM | 9620 | N | CYS | G | 680 | −19.072 | 62.955 | 37.001 | 1.00 | 13.40 | G | N |
| ATOM | 9621 | CA | CYS | G | 680 | −19.680 | 61.926 | 36.158 | 1.00 | 12.37 | G | C |
| ATOM | 9622 | CB | CYS | G | 680 | −20.591 | 62.583 | 35.115 | 1.00 | 13.04 | G | C |
| ATOM | 9623 | SG | CYS | G | 680 | −22.072 | 63.390 | 35.849 | 1.00 | 21.26 | G | S |
| ATOM | 9624 | C | CYS | G | 680 | −18.595 | 61.067 | 35.496 | 1.00 | 11.56 | G | C |
| ATOM | 9625 | O | CYS | G | 680 | −18.817 | 59.893 | 35.147 | 1.00 | 10.00 | G | O |
| ATOM | 9626 | N | GLU | G | 681 | −17.412 | 61.649 | 35.337 | 1.00 | 9.84 | G | N |
| ATOM | 9627 | CA | GLU | G | 681 | −16.299 | 60.909 | 34.763 | 1.00 | 10.55 | G | C |
| ATOM | 9628 | CB | GLU | G | 681 | −15.129 | 61.849 | 34.399 | 1.00 | 10.52 | G | C |
| ATOM | 9629 | CG | GLU | G | 681 | −13.967 | 61.110 | 33.709 | 1.00 | 13.92 | G | C |
| ATOM | 9630 | CD | GLU | G | 681 | −12.774 | 61.993 | 33.323 | 1.00 | 13.19 | G | C |
| ATOM | 9631 | OE1 | GLU | G | 681 | −12.601 | 63.112 | 33.858 | 1.00 | 12.78 | G | O |
| ATOM | 9632 | OE2 | GLU | G | 681 | −11.984 | 61.542 | 32.470 | 1.00 | 17.19 | G | O |
| ATOM | 9633 | C | GLU | G | 681 | −15.842 | 59.876 | 35.804 | 1.00 | 11.43 | G | C |
| ATOM | 9634 | O | GLU | G | 681 | −15.539 | 58.731 | 35.460 | 1.00 | 11.43 | G | O |
| ATOM | 9635 | N | VAL | G | 682 | −15.784 | 60.274 | 37.077 | 1.00 | 10.85 | G | N |
| ATOM | 9636 | CA | VAL | G | 682 | −15.363 | 59.346 | 38.129 | 1.00 | 8.68 | G | C |
| ATOM | 9637 | CB | VAL | G | 682 | −15.225 | 60.073 | 39.503 | 1.00 | 8.59 | G | C |
| ATOM | 9638 | CG1 | VAL | G | 682 | −15.097 | 59.049 | 40.645 | 1.00 | 7.49 | G | C |
| ATOM | 9639 | CG2 | VAL | G | 682 | −13.995 | 60.993 | 39.478 | 1.00 | 4.15 | G | C |
| ATOM | 9640 | C | VAL | G | 682 | −16.396 | 58.219 | 38.213 | 1.00 | 8.30 | G | C |
| ATOM | 9641 | O | VAL | G | 682 | −16.047 | 57.038 | 38.284 | 1.00 | 10.74 | G | O |
| ATOM | 9642 | N | ALA | G | 683 | −17.670 | 58.589 | 38.168 | 1.00 | 8.67 | G | N |
| ATOM | 9643 | CA | ALA | G | 683 | −18.756 | 57.615 | 38.221 | 1.00 | 7.11 | G | C |
| ATOM | 9644 | CB | ALA | G | 683 | −20.090 | 58.323 | 38.100 | 1.00 | 5.63 | G | C |
| ATOM | 9645 | C | ALA | G | 683 | −18.615 | 56.599 | 37.099 | 1.00 | 9.22 | G | C |
| ATOM | 9646 | O | ALA | G | 683 | −18.763 | 55.402 | 37.325 | 1.00 | 8.80 | G | O |
| ATOM | 9647 | N | ARG | G | 684 | −18.338 | 57.079 | 35.885 | 1.00 | 11.78 | G | N |
| ATOM | 9648 | CA | ARG | G | 684 | −18.187 | 56.190 | 34.720 | 1.00 | 11.38 | G | C |
| ATOM | 9649 | CB | ARG | G | 684 | −17.993 | 57.012 | 33.434 | 1.00 | 12.02 | G | C |
| ATOM | 9650 | CG | ARG | G | 684 | −17.826 | 56.167 | 32.163 | 1.00 | 11.27 | G | C |
| ATOM | 9651 | CD | ARG | G | 684 | −17.799 | 57.034 | 30.891 | 1.00 | 13.74 | G | C |
| ATOM | 9652 | NE | ARG | G | 684 | −17.765 | 56.234 | 29.665 | 1.00 | 14.34 | G | N |
| ATOM | 9653 | CZ | ARG | G | 684 | −16.642 | 55.813 | 29.092 | 1.00 | 16.12 | G | C |
| ATOM | 9654 | NH1 | ARG | G | 684 | −15.470 | 56.121 | 29.638 | 1.00 | 13.70 | G | N |
| ATOM | 9655 | NH2 | ARG | G | 684 | −16.685 | 55.079 | 27.981 | 1.00 | 17.93 | G | N |
| ATOM | 9656 | C | ARG | G | 684 | −16.999 | 55.254 | 34.930 | 1.00 | 10.99 | G | C |
| ATOM | 9657 | O | ARG | G | 684 | −17.092 | 54.059 | 34.660 | 1.00 | 11.13 | G | O |
| ATOM | 9658 | N | ASN | G | 685 | −15.880 | 55.798 | 35.405 | 1.00 | 10.87 | G | N |
| ATOM | 9659 | CA | ASN | G | 685 | −14.703 | 54.973 | 35.696 | 1.00 | 11.65 | G | C |
| ATOM | 9660 | CB | ASN | G | 685 | −13.562 | 55.817 | 36.292 | 1.00 | 12.76 | G | C |
| ATOM | 9661 | CG | ASN | G | 685 | −12.951 | 56.784 | 35.275 | 1.00 | 16.02 | G | C |
| ATOM | 9662 | OD1 | ASN | G | 685 | −13.205 | 56.690 | 34.077 | 1.00 | 15.86 | G | O |
| ATOM | 9663 | ND2 | ASN | G | 685 | −12.149 | 57.710 | 35.755 | 1.00 | 14.71 | G | N |
| ATOM | 9664 | C | ASN | G | 685 | −15.050 | 53.864 | 36.693 | 1.00 | 11.86 | G | C |
| ATOM | 9665 | O | ASN | G | 685 | −14.572 | 52.732 | 36.564 | 1.00 | 11.73 | G | O |
| ATOM | 9666 | N | SER | G | 686 | −15.878 | 54.180 | 37.687 | 1.00 | 10.38 | G | N |
| ATOM | 9667 | CA | SER | G | 686 | −16.250 | 53.167 | 38.671 | 1.00 | 9.91 | G | C |
| ATOM | 9668 | CB | SER | G | 686 | −17.035 | 53.804 | 39.833 | 1.00 | 7.99 | G | C |
| ATOM | 9669 | OG | SER | G | 686 | −18.395 | 54.069 | 39.531 | 1.00 | 8.81 | G | O |
| ATOM | 9670 | C | SER | G | 686 | −17.028 | 52.015 | 38.031 | 1.00 | 11.22 | G | C |
| ATOM | 9671 | O | SER | G | 686 | −16.794 | 50.852 | 38.373 | 1.00 | 13.61 | G | O |
| ATOM | 9672 | N | VAL | G | 687 | −17.925 | 52.313 | 37.089 | 1.00 | 11.60 | G | N |
| ATOM | 9673 | CA | VAL | G | 687 | −18.688 | 51.250 | 36.421 | 1.00 | 10.47 | G | C |
| ATOM | 9674 | CB | VAL | G | 687 | −19.850 | 51.796 | 35.551 | 1.00 | 10.80 | G | C |
| ATOM | 9675 | CG1 | VAL | G | 687 | −20.706 | 50.624 | 35.060 | 1.00 | 10.30 | G | C |
| ATOM | 9676 | CG2 | VAL | G | 687 | −20.730 | 52.737 | 36.365 | 1.00 | 8.89 | G | C |
| ATOM | 9677 | C | VAL | G | 687 | −17.778 | 50.409 | 35.538 | 1.00 | 11.13 | G | C |
| ATOM | 9678 | O | VAL | G | 687 | −17.907 | 49.187 | 35.488 | 1.00 | 12.13 | G | O |
| ATOM | 9679 | N | LEU | G | 688 | −16.848 | 51.063 | 34.853 | 1.00 | 11.56 | G | N |
| ATOM | 9680 | CA | LEU | G | 688 | −15.885 | 50.368 | 33.998 | 1.00 | 11.41 | G | C |
| ATOM | 9681 | CB | LEU | G | 688 | −14.996 | 51.382 | 33.267 | 1.00 | 6.08 | G | C |
| ATOM | 9682 | CG | LEU | G | 688 | −15.604 | 52.194 | 32.121 | 1.00 | 13.00 | G | C |
| ATOM | 9683 | CD1 | LEU | G | 688 | −14.580 | 53.183 | 31.569 | 1.00 | 7.27 | G | C |
| ATOM | 9684 | CD2 | LEU | G | 688 | −16.081 | 51.238 | 31.027 | 1.00 | 8.60 | G | C |
| ATOM | 9685 | C | LEU | G | 688 | −14.979 | 49.456 | 34.846 | 1.00 | 12.37 | G | C |
| ATOM | 9686 | O | LEU | G | 688 | −14.630 | 48.344 | 34.444 | 1.00 | 12.60 | G | O |
| ATOM | 9687 | N | GLN | G | 689 | −14.573 | 49.948 | 36.010 | 1.00 | 11.76 | G | N |
| ATOM | 9688 | CA | GLN | G | 689 | −13.696 | 49.203 | 36.911 | 1.00 | 10.41 | G | C |
| ATOM | 9689 | CB | GLN | G | 689 | −13.160 | 50.151 | 37.994 | 1.00 | 10.95 | G | C |
| ATOM | 9690 | CG | GLN | G | 689 | −12.340 | 49.444 | 39.059 | 1.00 | 10.71 | G | C |
| ATOM | 9691 | CD | GLN | G | 689 | −11.621 | 50.382 | 40.011 | 1.00 | 7.48 | G | C |
| ATOM | 9692 | OE1 | GLN | G | 689 | −10.737 | 49.958 | 40.743 | 1.00 | 15.70 | G | O |
| ATOM | 9693 | NE2 | GLN | G | 689 | −11.999 | 51.649 | 40.015 | 1.00 | 9.36 | G | N |
| ATOM | 9694 | C | GLN | G | 689 | −14.326 | 47.975 | 37.600 | 1.00 | 11.42 | G | C |
| ATOM | 9695 | O | GLN | G | 689 | −13.676 | 46.937 | 37.728 | 1.00 | 12.23 | G | O |
| ATOM | 9696 | N | CYS | G | 690 | −15.586 | 48.090 | 38.023 | 1.00 | 13.93 | G | N |
| ATOM | 9697 | CA | CYS | G | 690 | −16.271 | 47.022 | 38.749 | 1.00 | 13.70 | G | C |
| ATOM | 9698 | CB | CYS | G | 690 | −17.583 | 47.557 | 39.309 | 1.00 | 13.87 | G | C |
| ATOM | 9699 | SG | CYS | G | 690 | −18.884 | 47.730 | 38.098 | 1.00 | 15.64 | G | S |
| ATOM | 9700 | C | CYS | G | 690 | −16.531 | 45.682 | 38.053 | 1.00 | 17.40 | G | C |
| ATOM | 9701 | O | CYS | G | 690 | −16.308 | 45.534 | 36.852 | 1.00 | 18.09 | G | O |
| ATOM | 9702 | N | GLY | G | 691 | −17.019 | 44.713 | 38.831 | 1.00 | 14.73 | G | N |
| ATOM | 9703 | CA | GLY | G | 691 | −17.308 | 43.390 | 38.312 | 1.00 | 14.05 | G | C |
| ATOM | 9704 | C | GLY | G | 691 | −18.751 | 43.146 | 37.898 | 1.00 | 16.15 | G | C |
| ATOM | 9705 | O | GLY | G | 691 | −19.184 | 41.995 | 37.795 | 1.00 | 20.26 | G | O |
| ATOM | 9706 | N | ILE | G | 692 | −19.501 | 44.214 | 37.657 | 1.00 | 15.23 | G | N |
| ATOM | 9707 | CA | ILE | G | 692 | −20.882 | 44.075 | 37.229 | 1.00 | 16.51 | G | C |
| ATOM | 9708 | CB | ILE | G | 692 | −21.540 | 45.458 | 37.185 | 1.00 | 15.04 | G | C |
| ATOM | 9709 | CG2 | ILE | G | 692 | −22.845 | 45.423 | 36.378 | 1.00 | 13.41 | G | C |
| ATOM | 9710 | CG1 | ILE | G | 692 | −21.805 | 45.902 | 38.621 | 1.00 | 15.21 | G | C |
| ATOM | 9711 | CD1 | ILE | G | 692 | −22.462 | 47.263 | 38.748 | 1.00 | 13.75 | G | C |
| ATOM | 9712 | C | ILE | G | 692 | −20.938 | 43.357 | 35.859 | 1.00 | 16.22 | G | C |
| ATOM | 9713 | O | ILE | G | 692 | −19.967 | 43.385 | 35.102 | 1.00 | 15.35 | G | O |
| ATOM | 9714 | N | SER | G | 693 | −22.054 | 42.688 | 35.560 | 1.00 | 15.26 | G | N |
| ATOM | 9715 | CA | SER | G | 693 | −22.180 | 41.943 | 34.303 | 1.00 | 15.89 | G | C |
| ATOM | 9716 | CB | SER | G | 693 | −23.475 | 41.149 | 34.279 | 1.00 | 15.07 | G | C |
| ATOM | 9717 | OG | SER | G | 693 | −24.570 | 42.010 | 34.039 | 1.00 | 21.15 | G | O |
| ATOM | 9718 | C | SER | G | 693 | −22.126 | 42.824 | 33.067 | 1.00 | 17.24 | G | C |
| ATOM | 9719 | O | SER | G | 693 | −22.482 | 44.009 | 33.115 | 1.00 | 16.16 | G | O |
| ATOM | 9720 | N | HIS | G | 694 | −21.685 | 42.234 | 31.955 | 1.00 | 19.79 | G | N |
| ATOM | 9721 | CA | HIS | G | 694 | −21.580 | 42.964 | 30.692 | 1.00 | 22.84 | G | C |
| ATOM | 9722 | CB | HIS | G | 694 | −21.019 | 42.058 | 29.588 | 1.00 | 24.27 | G | C |
| ATOM | 9723 | CG | HIS | G | 694 | −20.983 | 42.710 | 28.238 | 1.00 | 26.90 | G | C |
| ATOM | 9724 | CD2 | HIS | G | 694 | −20.203 | 43.703 | 27.751 | 1.00 | 26.90 | G | C |
| ATOM | 9725 | ND1 | HIS | G | 694 | −21.859 | 42.381 | 27.224 | 1.00 | 29.56 | G | N |
| ATOM | 9726 | CE1 | HIS | G | 694 | −21.622 | 43.143 | 26.173 | 1.00 | 25.77 | G | C |
| ATOM | 9727 | NE2 | HIS | G | 694 | −20.622 | 43.954 | 26.468 | 1.00 | 30.54 | G | N |
| ATOM | 9728 | C | HIS | G | 694 | −22.919 | 43.541 | 30.245 | 1.00 | 21.07 | G | C |
| ATOM | 9729 | O | HIS | G | 694 | −22.978 | 44.670 | 29.762 | 1.00 | 19.59 | G | O |
| ATOM | 9730 | N | GLU | G | 695 | −23.987 | 42.767 | 30.420 | 1.00 | 22.00 | G | N |
| ATOM | 9731 | CA | GLU | G | 695 | −25.322 | 43.199 | 30.026 | 1.00 | 24.98 | G | C |
| ATOM | 9732 | CB | GLU | G | 695 | −26.348 | 42.071 | 30.266 | 1.00 | 33.71 | G | C |
| ATOM | 9733 | CG | GLU | G | 695 | −27.805 | 42.415 | 29.844 | 1.00 | 47.17 | G | C |
| ATOM | 9734 | CD | GLU | G | 695 | −28.883 | 42.120 | 30.931 | 1.00 | 54.72 | G | C |
| ATOM | 9735 | OE1 | GLU | G | 695 | −29.421 | 40.981 | 30.945 | 1.00 | 56.77 | G | O |
| ATOM | 9736 | OE2 | GLU | G | 695 | −29.201 | 43.025 | 31.756 | 1.00 | 54.33 | G | O |
| ATOM | 9737 | C | GLU | G | 695 | −25.751 | 44.450 | 30.769 | 1.00 | 22.48 | G | C |
| ATOM | 9738 | O | GLU | G | 695 | −26.324 | 45.364 | 30.175 | 1.00 | 22.89 | G | O |
| ATOM | 9739 | N | GLU | G | 696 | −25.476 | 44.506 | 32.066 | 1.00 | 20.07 | G | N |
| ATOM | 9740 | CA | GLU | G | 696 | −25.885 | 45.670 | 32.848 | 1.00 | 20.55 | G | C |
| ATOM | 9741 | CB | GLU | G | 696 | −25.854 | 45.344 | 34.330 | 1.00 | 21.55 | G | C |
| ATOM | 9742 | CG | GLU | G | 696 | −27.027 | 44.520 | 34.757 | 1.00 | 30.39 | G | C |
| ATOM | 9743 | CD | GLU | G | 696 | −26.757 | 43.818 | 36.067 | 1.00 | 40.97 | G | C |
| ATOM | 9744 | OE1 | GLU | G | 696 | −27.206 | 44.350 | 37.125 | 1.00 | 41.09 | G | O |
| ATOM | 9745 | OE2 | GLU | G | 696 | −26.086 | 42.746 | 36.030 | 1.00 | 39.77 | G | O |
| ATOM | 9746 | C | GLU | G | 696 | −25.027 | 46.885 | 32.570 | 1.00 | 15.99 | G | C |
| ATOM | 9747 | O | GLU | G | 696 | −25.520 | 48.010 | 32.567 | 1.00 | 15.53 | G | O |
| ATOM | 9748 | N | LYS | G | 697 | −23.741 | 46.658 | 32.342 | 1.00 | 15.61 | G | N |
| ATOM | 9749 | CA | LYS | G | 697 | −22.840 | 47.761 | 32.049 | 1.00 | 20.43 | G | C |
| ATOM | 9750 | CB | LYS | G | 697 | −21.404 | 47.274 | 31.981 | 1.00 | 18.07 | G | C |
| ATOM | 9751 | CG | LYS | G | 697 | −20.781 | 47.095 | 33.340 | 1.00 | 19.30 | G | C |
| ATOM | 9752 | CD | LYS | G | 697 | −19.306 | 46.873 | 33.197 | 1.00 | 17.52 | G | C |
| ATOM | 9753 | CE | LYS | G | 697 | −18.705 | 46.384 | 34.479 | 1.00 | 16.21 | G | C |
| ATOM | 9754 | NZ | LYS | G | 697 | −17.250 | 46.196 | 34.293 | 1.00 | 17.89 | G | N |
| ATOM | 9755 | C | LYS | G | 697 | −23.219 | 48.424 | 30.730 | 1.00 | 22.04 | G | C |
| ATOM | 9756 | O | LYS | G | 697 | −23.225 | 49.647 | 30.627 | 1.00 | 25.10 | G | O |
| ATOM | 9757 | N | ALA | G | 698 | −23.545 | 47.619 | 29.723 | 1.00 | 21.59 | G | N |
| ATOM | 9758 | CA | ALA | G | 698 | −23.941 | 48.169 | 28.430 | 1.00 | 22.17 | G | C |
| ATOM | 9759 | CB | ALA | G | 698 | −24.240 | 47.029 | 27.434 | 1.00 | 19.37 | G | C |
| ATOM | 9760 | C | ALA | G | 698 | −25.185 | 49.021 | 28.659 | 1.00 | 21.61 | G | C |
| ATOM | 9761 | O | ALA | G | 698 | −25.389 | 50.041 | 27.999 | 1.00 | 19.97 | G | O |
| ATOM | 9762 | N | LYS | G | 699 | −26.009 | 48.596 | 29.616 | 1.00 | 23.00 | G | N |
| ATOM | 9763 | CA | LYS | G | 699 | −27.238 | 49.305 | 29.960 | 1.00 | 22.14 | G | C |
| ATOM | 9764 | CB | LYS | G | 699 | −28.113 | 48.421 | 30.850 | 1.00 | 25.29 | G | C |
| ATOM | 9765 | CG | LYS | G | 699 | −29.397 | 49.090 | 31.326 | 1.00 | 28.90 | G | C |
| ATOM | 9766 | CD | LYS | G | 699 | −30.251 | 48.126 | 32.152 | 1.00 | 33.78 | G | C |
| ATOM | 9767 | CE | LYS | G | 699 | −30.706 | 48.747 | 33.479 | 1.00 | 32.27 | G | C |
| ATOM | 9768 | NZ | LYS | G | 699 | −31.652 | 49.866 | 33.262 | 1.00 | 31.90 | G | N |
| ATOM | 9769 | C | LYS | G | 699 | −26.995 | 50.642 | 30.657 | 1.00 | 20.90 | G | C |
| ATOM | 9770 | O | LYS | G | 699 | −27.686 | 51.619 | 30.377 | 1.00 | 20.28 | G | O |
| ATOM | 9771 | N | PHE | G | 700 | −26.015 | 50.681 | 31.562 | 1.00 | 21.21 | G | N |
| ATOM | 9772 | CA | PHE | G | 700 | −25.690 | 51.907 | 32.310 | 1.00 | 19.59 | G | C |
| ATOM | 9773 | CB | PHE | G | 700 | −24.947 | 51.569 | 33.615 | 1.00 | 17.14 | G | C |
| ATOM | 9774 | CG | PHE | G | 700 | −25.672 | 50.601 | 34.516 | 1.00 | 18.16 | G | C |
| ATOM | 9775 | CD1 | PHE | G | 700 | −27.064 | 50.555 | 34.548 | 1.00 | 16.00 | G | C |
| ATOM | 9776 | CD2 | PHE | G | 700 | −24.946 | 49.736 | 35.346 | 1.00 | 16.93 | G | C |
| ATOM | 9777 | CE1 | PHE | G | 700 | −27.734 | 49.659 | 35.395 | 1.00 | 14.86 | G | C |
| ATOM | 9778 | CE2 | PHE | G | 700 | −25.593 | 48.839 | 36.191 | 1.00 | 15.85 | G | C |
| ATOM | 9779 | CZ | PHE | G | 700 | −26.999 | 48.799 | 36.216 | 1.00 | 12.98 | G | C |
| ATOM | 9780 | C | PHE | G | 700 | −24.814 | 52.888 | 31.530 | 1.00 | 17.42 | G | C |
| ATOM | 9781 | O | PHE | G | 700 | −24.953 | 54.109 | 31.662 | 1.00 | 15.73 | G | O |
| ATOM | 9782 | N | LEU | G | 701 | −23.907 | 52.338 | 30.727 | 1.00 | 15.51 | G | N |
| ATOM | 9783 | CA | LEU | G | 701 | −22.943 | 53.134 | 29.977 | 1.00 | 16.86 | G | C |
| ATOM | 9784 | CB | LEU | G | 701 | −21.543 | 52.579 | 30.240 | 1.00 | 14.85 | G | C |
| ATOM | 9785 | CG | LEU | G | 701 | −21.071 | 52.438 | 31.688 | 1.00 | 13.20 | G | C |
| ATOM | 9786 | CD1 | LEU | G | 701 | −19.680 | 51.833 | 31.678 | 1.00 | 12.05 | G | C |
| ATOM | 9787 | CD2 | LEU | G | 701 | −21.045 | 53.800 | 32.368 | 1.00 | 7.80 | G | C |
| ATOM | 9788 | C | LEU | G | 701 | −23.125 | 53.253 | 28.462 | 1.00 | 17.86 | G | C |
| ATOM | 9789 | O | LEU | G | 701 | −22.554 | 54.148 | 27.836 | 1.00 | 15.32 | G | O |
| ATOM | 9790 | N | GLY | G | 702 | −23.906 | 52.349 | 27.881 | 1.00 | 19.52 | G | N |
| ATOM | 9791 | CA | GLY | G | 702 | −24.112 | 52.346 | 26.443 | 1.00 | 20.65 | G | C |
| ATOM | 9792 | C | GLY | G | 702 | −23.514 | 51.064 | 25.872 | 1.00 | 22.17 | G | C |
| ATOM | 9793 | O | GLY | G | 702 | −22.535 | 50.520 | 26.396 | 1.00 | 21.12 | G | O |
| ATOM | 9794 | N | ASN | G | 703 | −24.085 | 50.582 | 24.776 | 1.00 | 24.32 | G | N |
| ATOM | 9795 | CA | ASN | G | 703 | −23.628 | 49.337 | 24.161 | 1.00 | 23.90 | G | C |
| ATOM | 9796 | CB | ASN | G | 703 | −24.570 | 48.962 | 23.029 | 1.00 | 25.15 | G | C |
| ATOM | 9797 | CG | ASN | G | 703 | −25.950 | 48.629 | 23.528 | 1.00 | 31.41 | G | C |
| ATOM | 9798 | OD1 | ASN | G | 703 | −26.121 | 47.752 | 24.381 | 1.00 | 35.53 | G | O |
| ATOM | 9799 | ND2 | ASN | G | 703 | −26.945 | 49.329 | 23.013 | 1.00 | 33.68 | G | N |
| ATOM | 9800 | C | ASN | G | 703 | −22.192 | 49.248 | 23.668 | 1.00 | 23.36 | G | C |
| ATOM | 9801 | O | ASN | G | 703 | −21.659 | 48.153 | 23.538 | 1.00 | 24.55 | G | O |
| ATOM | 9802 | N | ASN | G | 704 | −21.550 | 50.379 | 23.413 | 1.00 | 22.24 | G | N |
| ATOM | 9803 | CA | ASN | G | 704 | −20.183 | 50.362 | 22.919 | 1.00 | 21.44 | G | C |
| ATOM | 9804 | CB | ASN | G | 704 | −20.065 | 51.330 | 21.755 | 1.00 | 29.64 | G | C |
| ATOM | 9805 | CG | ASN | G | 704 | −19.645 | 50.648 | 20.484 | 1.00 | 36.35 | G | C |
| ATOM | 9806 | OD1 | ASN | G | 704 | −18.457 | 50.634 | 20.133 | 1.00 | 37.26 | G | O |
| ATOM | 9807 | ND2 | ASN | G | 704 | −20.617 | 50.070 | 19.778 | 1.00 | 39.47 | G | N |
| ATOM | 9808 | C | ASN | G | 704 | −19.153 | 50.744 | 23.967 | 1.00 | 20.58 | G | C |
| ATOM | 9809 | O | ASN | G | 704 | −18.018 | 51.087 | 23.630 | 1.00 | 16.55 | G | O |
| ATOM | 9810 | N | TYR | G | 705 | −19.551 | 50.674 | 25.233 | 1.00 | 21.21 | G | N |
| ATOM | 9811 | CA | TYR | G | 705 | −18.684 | 51.057 | 26.351 | 1.00 | 19.10 | G | C |
| ATOM | 9812 | CB | TYR | G | 705 | −19.430 | 50.835 | 27.679 | 1.00 | 17.81 | G | C |
| ATOM | 9813 | CG | TYR | G | 705 | −19.384 | 49.411 | 28.184 | 1.00 | 14.23 | G | C |
| ATOM | 9814 | CD1 | TYR | G | 705 | −20.367 | 48.495 | 27.829 | 1.00 | 14.84 | G | C |
| ATOM | 9815 | CE1 | TYR | G | 705 | −20.304 | 47.175 | 28.259 | 1.00 | 14.60 | G | C |
| ATOM | 9816 | CD2 | TYR | G | 705 | −18.332 | 48.975 | 28.989 | 1.00 | 13.12 | G | C |
| ATOM | 9817 | CE2 | TYR | G | 705 | −18.255 | 47.659 | 29.426 | 1.00 | 14.36 | G | C |
| ATOM | 9818 | CZ | TYR | G | 705 | −19.241 | 46.766 | 29.056 | 1.00 | 15.43 | G | C |
| ATOM | 9819 | OH | TYR | G | 705 | −19.145 | 45.465 | 29.470 | 1.00 | 16.35 | G | O |
| ATOM | 9820 | C | TYR | G | 705 | −17.317 | 50.379 | 26.401 | 1.00 | 18.72 | G | C |
| ATOM | 9821 | O | TYR | G | 705 | −16.398 | 50.885 | 27.037 | 1.00 | 19.75 | G | O |
| ATOM | 9822 | N | LEU | G | 706 | −17.167 | 49.239 | 25.738 | 1.00 | 19.46 | G | N |
| ATOM | 9823 | CA | LEU | G | 706 | −15.885 | 48.549 | 25.763 | 1.00 | 21.36 | G | C |
| ATOM | 9824 | CB | LEU | G | 706 | −16.074 | 47.065 | 25.441 | 1.00 | 20.95 | G | C |
| ATOM | 9825 | CG | LEU | G | 706 | −16.509 | 46.178 | 26.605 | 1.00 | 20.01 | G | C |
| ATOM | 9826 | CD1 | LEU | G | 706 | −16.999 | 44.840 | 26.064 | 1.00 | 21.16 | G | C |
| ATOM | 9827 | CD2 | LEU | G | 706 | −15.350 | 45.971 | 27.554 | 1.00 | 17.61 | G | C |
| ATOM | 9828 | C | LEU | G | 706 | −14.877 | 49.170 | 24.796 | 1.00 | 23.33 | G | C |
| ATOM | 9829 | O | LEU | G | 706 | −13.685 | 48.855 | 24.839 | 1.00 | 25.49 | G | O |
| ATOM | 9830 | N | GLU | G | 707 | −15.359 | 50.048 | 23.924 | 1.00 | 23.05 | G | N |
| ATOM | 9831 | CA | GLU | G | 707 | −14.495 | 50.724 | 22.962 | 1.00 | 23.69 | G | C |
| ATOM | 9832 | CB | GLU | G | 707 | −15.322 | 51.192 | 21.758 | 1.00 | 28.43 | G | C |
| ATOM | 9833 | CG | GLU | G | 707 | −15.783 | 50.062 | 20.847 | 1.00 | 34.42 | G | C |
| ATOM | 9834 | CD | GLU | G | 707 | −14.716 | 48.985 | 20.672 | 1.00 | 41.50 | G | C |
| ATOM | 9835 | OE1 | GLU | G | 707 | −15.009 | 47.791 | 20.938 | 1.00 | 43.49 | G | O |
| ATOM | 9836 | OE2 | GLU | G | 707 | −13.580 | 49.339 | 20.273 | 1.00 | 43.06 | G | O |
| ATOM | 9837 | C | GLU | G | 707 | −13.861 | 51.925 | 23.655 | 1.00 | 23.51 | G | C |
| ATOM | 9838 | O | GLU | G | 707 | −14.531 | 52.632 | 24.402 | 1.00 | 23.12 | G | O |
| ATOM | 9839 | N | GLU | G | 708 | −12.581 | 52.162 | 23.401 | 1.00 | 21.91 | G | N |
| ATOM | 9840 | CA | GLU | G | 708 | −11.866 | 53.267 | 24.032 | 1.00 | 23.90 | G | C |
| ATOM | 9841 | CB | GLU | G | 708 | −10.388 | 52.897 | 24.199 | 1.00 | 24.68 | G | C |
| ATOM | 9842 | CG | GLU | G | 708 | −10.154 | 51.391 | 24.085 | 1.00 | 31.65 | G | C |
| ATOM | 9843 | CD | GLU | G | 708 | −9.069 | 50.856 | 24.991 | 1.00 | 32.86 | G | C |
| ATOM | 9844 | OE1 | GLU | G | 708 | −8.017 | 51.505 | 25.112 | 1.00 | 34.16 | G | O |
| ATOM | 9845 | OE2 | GLU | G | 708 | −9.266 | 49.766 | 25.573 | 1.00 | 36.86 | G | O |
| ATOM | 9846 | C | GLU | G | 708 | −12.015 | 54.589 | 23.286 | 1.00 | 22.68 | G | C |
| ATOM | 9847 | O | GLU | G | 708 | −12.181 | 54.616 | 22.074 | 1.00 | 23.33 | G | O |
| ATOM | 9848 | N | GLY | G | 709 | −11.975 | 55.688 | 24.032 | 1.00 | 20.69 | G | N |
| ATOM | 9849 | CA | GLY | G | 709 | −12.126 | 56.997 | 23.426 | 1.00 | 16.58 | G | C |
| ATOM | 9850 | C | GLY | G | 709 | −13.584 | 57.390 | 23.336 | 1.00 | 14.76 | G | C |
| ATOM | 9851 | O | GLY | G | 709 | −14.458 | 56.663 | 23.822 | 1.00 | 13.36 | G | O |
| ATOM | 9852 | N | PRO | G | 710 | −13.876 | 58.534 | 22.704 | 1.00 | 14.34 | G | N |
| ATOM | 9853 | CD | PRO | G | 710 | −12.858 | 59.407 | 22.095 | 1.00 | 12.48 | G | C |
| ATOM | 9854 | CA | PRO | G | 710 | −15.227 | 59.073 | 22.528 | 1.00 | 14.42 | G | C |
| ATOM | 9855 | CB | PRO | G | 710 | −15.005 | 60.308 | 21.665 | 1.00 | 13.02 | G | C |
| ATOM | 9856 | CG | PRO | G | 710 | −13.595 | 60.688 | 21.914 | 1.00 | 10.88 | G | C |
| ATOM | 9857 | C | PRO | G | 710 | −16.233 | 58.106 | 21.903 | 1.00 | 15.95 | G | C |
| ATOM | 9858 | O | PRO | G | 710 | −17.433 | 58.184 | 22.169 | 1.00 | 18.05 | G | O |
| ATOM | 9859 | N | ILE | G | 711 | −15.748 | 57.199 | 21.068 | 1.00 | 16.06 | G | N |
| ATOM | 9860 | CA | ILE | G | 711 | −16.624 | 56.241 | 20.429 | 1.00 | 17.25 | G | C |
| ATOM | 9861 | CB | ILE | G | 711 | −15.850 | 55.411 | 19.350 | 1.00 | 19.20 | G | C |
| ATOM | 9862 | CG2 | ILE | G | 711 | −15.141 | 54.209 | 19.968 | 1.00 | 16.76 | G | C |
| ATOM | 9863 | CG1 | ILE | G | 711 | −16.829 | 54.908 | 18.292 | 1.00 | 21.59 | G | C |
| ATOM | 9864 | CD1 | ILE | G | 711 | −17.756 | 56.001 | 17.742 | 1.00 | 21.75 | G | C |
| ATOM | 9865 | C | ILE | G | 711 | −17.285 | 55.312 | 21.457 | 1.00 | 18.45 | G | C |
| ATOM | 9866 | O | ILE | G | 711 | −18.387 | 54.809 | 21.227 | 1.00 | 21.60 | G | O |
| ATOM | 9867 | N | GLY | G | 712 | −16.632 | 55.100 | 22.596 | 1.00 | 17.49 | G | N |
| ATOM | 9868 | CA | GLY | G | 712 | −17.205 | 54.229 | 23.609 | 1.00 | 16.90 | G | C |
| ATOM | 9869 | C | GLY | G | 712 | −18.130 | 54.928 | 24.593 | 1.00 | 18.42 | G | C |
| ATOM | 9870 | O | GLY | G | 712 | −18.774 | 54.277 | 25.415 | 1.00 | 21.83 | G | O |
| ATOM | 9871 | N | ASN | G | 713 | −18.227 | 56.247 | 24.512 | 1.00 | 16.03 | G | N |
| ATOM | 9872 | CA | ASN | G | 713 | −19.062 | 56.983 | 25.452 | 1.00 | 14.50 | G | C |
| ATOM | 9873 | CB | ASN | G | 713 | −18.328 | 58.235 | 25.962 | 1.00 | 11.97 | G | C |
| ATOM | 9874 | CG | ASN | G | 713 | −19.159 | 59.037 | 26.949 | 1.00 | 11.69 | G | C |
| ATOM | 9875 | OD1 | ASN | G | 713 | −19.302 | 60.251 | 26.815 | 1.00 | 16.57 | G | O |
| ATOM | 9876 | ND2 | ASN | G | 713 | −19.717 | 58.364 | 27.939 | 1.00 | 8.63 | G | N |
| ATOM | 9877 | C | ASN | G | 713 | −20.384 | 57.408 | 24.882 | 1.00 | 15.15 | G | C |
| ATOM | 9878 | O | ASN | G | 713 | −20.442 | 58.002 | 23.812 | 1.00 | 16.04 | G | O |
| ATOM | 9879 | N | ASP | G | 714 | −21.447 | 57.111 | 25.618 | 1.00 | 16.28 | G | N |
| ATOM | 9880 | CA | ASP | G | 714 | −22.797 | 57.498 | 25.228 | 1.00 | 15.62 | G | C |
| ATOM | 9881 | CB | ASP | G | 714 | −23.702 | 56.265 | 25.220 | 1.00 | 17.09 | G | C |
| ATOM | 9882 | CG | ASP | G | 714 | −25.114 | 56.577 | 24.768 | 1.00 | 19.58 | G | C |
| ATOM | 9883 | OD1 | ASP | G | 714 | −25.468 | 57.781 | 24.680 | 1.00 | 19.41 | G | O |
| ATOM | 9884 | OD2 | ASP | G | 714 | −25.869 | 55.610 | 24.503 | 1.00 | 19.03 | G | O |
| ATOM | 9885 | C | ASP | G | 714 | −23.247 | 58.499 | 26.300 | 1.00 | 15.44 | G | C |
| ATOM | 9886 | O | ASP | G | 714 | −23.715 | 58.104 | 27.362 | 1.00 | 14.02 | G | O |
| ATOM | 9887 | N | ILE | G | 715 | −23.098 | 59.791 | 26.016 | 1.00 | 13.48 | G | N |
| ATOM | 9888 | CA | ILE | G | 715 | −23.442 | 60.836 | 26.969 | 1.00 | 14.51 | G | C |
| ATOM | 9889 | CB | ILE | G | 715 | −23.174 | 62.251 | 26.366 | 1.00 | 15.78 | G | C |
| ATOM | 9890 | CG2 | ILE | G | 715 | −24.174 | 62.550 | 25.247 | 1.00 | 12.78 | G | C |
| ATOM | 9891 | CD1 | ILE | G | 715 | −23.267 | 63.322 | 27.464 | 1.00 | 12.34 | G | C |
| ATOM | 9892 | CD1 | ILE | G | 715 | −22.912 | 64.718 | 26.984 | 1.00 | 6.89 | G | C |
| ATOM | 9893 | C | ILE | G | 715 | −24.873 | 60.765 | 27.469 | 1.00 | 16.34 | G | C |
| ATOM | 9894 | O | ILE | G | 715 | −25.178 | 61.198 | 28.587 | 1.00 | 17.74 | G | O |
| ATOM | 9895 | N | ARG | G | 716 | −25.761 | 60.223 | 26.651 | 1.00 | 16.44 | G | N |
| ATOM | 9896 | CA | ARG | G | 716 | −27.155 | 60.119 | 27.055 | 1.00 | 18.94 | G | C |
| ATOM | 9897 | CB | ARG | G | 716 | −28.015 | 59.581 | 25.907 | 1.00 | 21.52 | G | C |
| ATOM | 9898 | CG | ARG | G | 716 | −28.396 | 60.623 | 24.867 | 1.00 | 28.51 | G | C |
| ATOM | 9899 | CD | ARG | G | 716 | −28.882 | 59.954 | 23.587 | 1.00 | 36.66 | G | C |
| ATOM | 9900 | NE | ARG | G | 716 | −28.089 | 58.762 | 23.264 | 1.00 | 44.58 | G | N |
| ATOM | 9901 | CZ | ARG | G | 716 | −28.482 | 57.779 | 22.449 | 1.00 | 46.60 | G | C |
| ATOM | 9902 | NH1 | ARG | G | 716 | −29.668 | 57.825 | 21.853 | 1.00 | 45.95 | G | N |
| ATOM | 9903 | NH2 | ARG | G | 716 | −27.685 | 56.740 | 22.229 | 1.00 | 46.57 | G | N |
| ATOM | 9904 | C | ARG | G | 716 | −27.286 | 59.200 | 28.264 | 1.00 | 18.97 | G | C |
| ATOM | 9905 | O | ARG | G | 716 | −28.282 | 59.255 | 28.976 | 1.00 | 20.26 | G | O |
| ATOM | 9906 | N | LYS | G | 717 | −26.277 | 58.362 | 28.486 | 1.00 | 17.51 | G | N |
| ATOM | 9907 | CA | LYS | G | 717 | −26.273 | 57.431 | 29.607 | 1.00 | 18.17 | G | C |
| ATOM | 9908 | CB | LYS | G | 717 | −25.956 | 56.025 | 29.094 | 1.00 | 18.19 | G | C |
| ATOM | 9909 | CG | LYS | G | 717 | −27.152 | 55.394 | 28.386 | 1.00 | 21.39 | G | C |
| ATOM | 9910 | CD | LYS | G | 717 | −26.838 | 54.028 | 27.854 | 1.00 | 24.88 | G | C |
| ATOM | 9911 | CE | LYS | G | 717 | −28.131 | 53.281 | 27.546 | 1.00 | 29.20 | G | C |
| ATOM | 9912 | NZ | LYS | G | 717 | −27.891 | 52.003 | 26.776 | 1.00 | 33.97 | G | N |
| ATOM | 9913 | C | LYS | G | 717 | −25.307 | 57.789 | 30.740 | 1.00 | 18.08 | G | C |
| ATOM | 9914 | O | LYS | G | 717 | −25.590 | 57.531 | 31.916 | 1.00 | 16.92 | G | O |
| ATOM | 9915 | N | THR | G | 718 | −24.179 | 58.391 | 30.380 | 1.00 | 15.23 | G | N |
| ATOM | 9916 | CA | THR | G | 718 | −23.142 | 58.748 | 31.339 | 1.00 | 13.26 | G | C |
| ATOM | 9917 | CB | THR | G | 718 | −21.771 | 58.367 | 30.775 | 1.00 | 13.30 | G | C |
| ATOM | 9918 | OG1 | THR | G | 718 | −21.435 | 59.271 | 29.714 | 1.00 | 14.14 | G | O |
| ATOM | 9919 | CG2 | THR | G | 718 | −21.793 | 56.939 | 30.233 | 1.00 | 10.68 | G | C |
| ATOM | 9920 | C | THR | G | 718 | −23.053 | 60.212 | 31.782 | 1.00 | 15.01 | G | C |
| ATOM | 9921 | O | THR | G | 718 | −22.491 | 60.504 | 32.837 | 1.00 | 15.07 | G | O |
| ATOM | 9922 | N | ASN | G | 719 | −23.588 | 61.126 | 30.979 | 1.00 | 12.83 | G | N |
| ATOM | 9923 | CA | ASN | G | 719 | −23.507 | 62.553 | 31.262 | 1.00 | 12.01 | G | C |
| ATOM | 9924 | CB | ASN | G | 719 | −24.207 | 62.909 | 32.570 | 1.00 | 13.27 | G | C |
| ATOM | 9925 | CG | ASN | G | 719 | −24.674 | 64.355 | 32.593 | 1.00 | 16.38 | G | C |
| ATOM | 9926 | OD1 | ASN | G | 719 | −25.321 | 64.824 | 31.654 | 1.00 | 16.08 | G | O |
| ATOM | 9927 | ND2 | ASN | G | 719 | −24.337 | 65.075 | 33.660 | 1.00 | 18.29 | G | N |
| ATOM | 9928 | C | ASN | G | 719 | −22.065 | 63.052 | 31.304 | 1.00 | 10.92 | G | C |
| ATOM | 9929 | O | ASN | G | 719 | −21.769 | 64.061 | 31.935 | 1.00 | 13.07 | G | O |
| ATOM | 9930 | N | VAL | G | 720 | −21.162 | 62.333 | 30.649 | 1.00 | 11.71 | G | N |
| ATOM | 9931 | CA | VAL | G | 720 | −19.753 | 62.739 | 30.576 | 1.00 | 11.80 | G | C |
| ATOM | 9932 | CB | VAL | G | 720 | −18.803 | 61.501 | 30.627 | 1.00 | 13.89 | G | C |
| ATOM | 9933 | CG1 | VAL | G | 720 | −17.369 | 61.921 | 30.325 | 1.00 | 12.25 | G | C |
| ATOM | 9934 | CG2 | VAL | G | 720 | −18.886 | 60.825 | 32.004 | 1.00 | 8.57 | G | C |
| ATOM | 9935 | C | VAL | G | 720 | −19.605 | 63.439 | 29.211 | 1.00 | 13.42 | G | C |
| ATOM | 9936 | O | VAL | G | 720 | −20.014 | 62.888 | 28.185 | 1.00 | 13.33 | G | O |
| ATOM | 9937 | N | ALA | G | 721 | −19.029 | 64.638 | 29.196 | 1.00 | 11.68 | G | N |
| ATOM | 9938 | CA | ALA | G | 721 | −18.861 | 65.404 | 27.960 | 1.00 | 9.54 | G | C |
| ATOM | 9939 | CB | ALA | G | 721 | −18.280 | 66.780 | 28.289 | 1.00 | 6.38 | G | C |
| ATOM | 9940 | C | ALA | G | 721 | −17.970 | 64.691 | 26.944 | 1.00 | 10.83 | G | C |
| ATOM | 9941 | O | ALA | G | 721 | −16.969 | 64.081 | 27.311 | 1.00 | 11.68 | G | O |
| ATOM | 9942 | N | GLN | G | 722 | −18.322 | 64.767 | 25.663 | 1.00 | 11.61 | G | N |
| ATOM | 9943 | CA | GLN | G | 722 | −17.492 | 64.129 | 24.641 | 1.00 | 10.63 | G | C |
| ATOM | 9944 | CB | GLN | G | 722 | −18.226 | 64.099 | 23.295 | 1.00 | 12.96 | G | C |
| ATOM | 9945 | CG | GLN | G | 722 | −19.251 | 62.957 | 23.181 | 1.00 | 10.93 | G | C |
| ATOM | 9946 | CD | GLN | G | 722 | −18.614 | 61.570 | 23.248 | 1.00 | 14.88 | G | C |
| ATOM | 9947 | OE1 | GLN | G | 722 | −18.657 | 60.812 | 22.285 | 1.00 | 20.15 | G | O |
| ATOM | 9948 | NE2 | GLN | G | 722 | −18.027 | 61.234 | 24.379 | 1.00 | 14.65 | G | N |
| ATOM | 9949 | C | GLN | G | 722 | −16.167 | 64.897 | 24.544 | 1.00 | 9.28 | G | C |
| ATOM | 9950 | O | GLN | G | 722 | −15.136 | 64.340 | 24.175 | 1.00 | 9.25 | G | O |
| ATOM | 9951 | N | ILE | G | 723 | −16.192 | 66.178 | 24.900 | 1.00 | 10.74 | G | N |
| ATOM | 9952 | CA | ILE | G | 723 | −14.967 | 66.985 | 24.903 | 1.00 | 13.38 | G | C |
| ATOM | 9953 | CB | ILE | G | 723 | −15.269 | 68.436 | 25.353 | 1.00 | 13.77 | G | C |
| ATOM | 9954 | CG2 | ILE | G | 723 | −13.976 | 69.149 | 25.768 | 1.00 | 13.90 | G | C |
| ATOM | 9955 | CG1 | ILE | G | 723 | −15.958 | 69.198 | 24.220 | 1.00 | 13.29 | G | C |
| ATOM | 9956 | CD1 | ILE | G | 723 | −16.480 | 70.570 | 24.641 | 1.00 | 7.45 | G | C |
| ATOM | 9957 | C | ILE | G | 723 | −13.974 | 66.348 | 25.896 | 1.00 | 12.58 | G | C |
| ATOM | 9958 | O | ILE | G | 723 | −12.772 | 66.237 | 25.634 | 1.00 | 13.21 | G | O |
| ATOM | 9959 | N | ARG | G | 724 | −14.501 | 65.910 | 27.035 | 1.00 | 11.00 | G | N |
| ATOM | 9960 | CA | ARG | G | 724 | −13.675 | 65.292 | 28.058 | 1.00 | 10.07 | G | C |
| ATOM | 9961 | CB | ARG | G | 724 | −14.513 | 65.082 | 29.344 | 1.00 | 12.51 | G | C |
| ATOM | 9962 | CG | ARG | G | 724 | −13.740 | 64.518 | 30.562 | 1.00 | 10.95 | G | C |
| ATOM | 9963 | CD | ARG | G | 724 | −12.461 | 65.325 | 30.887 | 1.00 | 9.49 | G | C |
| ATOM | 9964 | NE | ARG | G | 724 | −12.787 | 66.629 | 31.444 | 1.00 | 12.47 | G | N |
| ATOM | 9965 | CZ | ARG | G | 724 | −13.052 | 66.858 | 32.729 | 1.00 | 14.28 | G | C |
| ATOM | 9966 | NH1 | ARG | G | 724 | −13.024 | 65.861 | 33.608 | 1.00 | 12.40 | G | N |
| ATOM | 9967 | NH2 | ARG | G | 724 | −13.386 | 68.079 | 33.131 | 1.00 | 11.04 | G | N |
| ATOM | 9968 | C | ARG | G | 724 | −13.130 | 63.980 | 27.520 | 1.00 | 8.10 | G | C |
| ATOM | 9969 | O | ARG | G | 724 | −11.943 | 63.689 | 27.667 | 1.00 | 8.30 | G | O |
| ATOM | 9970 | N | MET | G | 725 | −13.986 | 63.185 | 26.886 | 1.00 | 6.59 | G | N |
| ATOM | 9971 | CA | MET | G | 725 | −13.526 | 61.907 | 26.325 | 1.00 | 8.68 | G | C |
| ATOM | 9972 | CB | MET | G | 725 | −14.688 | 61.160 | 25.673 | 1.00 | 6.42 | G | C |
| ATOM | 9973 | CG | MET | G | 725 | −15.779 | 60.734 | 26.626 | 1.00 | 8.06 | G | C |
| ATOM | 9974 | SD | MET | G | 725 | −15.194 | 59.528 | 27.831 | 1.00 | 14.99 | G | S |
| ATOM | 9975 | CE | MET | G | 725 | −14.540 | 58.198 | 26.775 | 1.00 | 10.56 | G | C |
| ATOM | 9976 | C | MET | G | 725 | −12.410 | 62.109 | 25.281 | 1.00 | 9.71 | G | C |
| ATOM | 9977 | O | MET | G | 725 | −11.403 | 61.396 | 25.293 | 1.00 | 10.44 | G | O |
| ATOM | 9978 | N | ALA | G | 726 | −12.593 | 63.088 | 24.393 | 1.00 | 10.50 | G | N |
| ATOM | 9979 | CA | ALA | G | 726 | −11.617 | 63.378 | 23.341 | 1.00 | 13.02 | G | C |
| ATOM | 9980 | CB | ALA | G | 726 | −12.164 | 64.438 | 22.374 | 1.00 | 11.19 | G | C |
| ATOM | 9981 | C | ALA | G | 726 | −10.312 | 63.850 | 23.945 | 1.00 | 13.32 | G | C |
| ATOM | 9982 | O | ALA | G | 726 | −9.229 | 63.425 | 23.526 | 1.00 | 14.45 | G | O |
| ATOM | 9983 | N | TYR | G | 727 | −10.407 | 64.736 | 24.933 | 1.00 | 13.17 | G | N |
| ATOM | 9984 | CA | TYR | G | 727 | −9.202 | 65.229 | 25.583 | 1.00 | 10.43 | G | C |
| ATOM | 9985 | CB | TYR | G | 727 | −9.546 | 66.245 | 26.688 | 1.00 | 8.51 | G | C |
| ATOM | 9986 | CG | TYR | G | 727 | −8.322 | 66.615 | 27.508 | 1.00 | 12.18 | G | C |
| ATOM | 9987 | CD1 | TYR | G | 727 | −8.018 | 65.936 | 28.700 | 1.00 | 9.05 | G | C |
| ATOM | 9988 | CE1 | TYR | G | 727 | −6.850 | 66.231 | 29.424 | 1.00 | 11.54 | G | C |
| ATOM | 9989 | CD2 | TYR | G | 727 | −7.430 | 67.599 | 27.065 | 1.00 | 8.96 | G | C |
| ATOM | 9990 | CE2 | TYR | G | 727 | −6.257 | 67.901 | 27.791 | 1.00 | 11.14 | G | C |
| ATOM | 9991 | CZ | TYR | G | 727 | −5.979 | 67.208 | 28.968 | 1.00 | 11.33 | G | C |
| ATOM | 9992 | OH | TYR | G | 727 | −4.851 | 67.497 | 29.707 | 1.00 | 10.69 | G | O |
| ATOM | 9993 | C | TYR | G | 727 | −8.366 | 64.081 | 26.183 | 1.00 | 10.93 | G | C |
| ATOM | 9994 | O | TYR | G | 727 | −7.165 | 64.000 | 25.948 | 1.00 | 9.06 | G | O |
| ATOM | 9995 | N | ARG | G | 728 | −8.997 | 63.188 | 26.942 | 1.00 | 8.10 | G | N |
| ATOM | 9996 | CA | ARG | G | 728 | −8.265 | 62.105 | 27.562 | 1.00 | 7.04 | G | C |
| ATOM | 9997 | CB | ARG | G | 728 | −9.182 | 61.291 | 28.484 | 1.00 | 9.95 | G | C |
| ATOM | 9998 | CG | ARG | G | 728 | −9.836 | 62.072 | 29.619 | 1.00 | 13.03 | G | C |
| ATOM | 9999 | CD | ARG | G | 728 | −8.832 | 62.447 | 30.685 | 1.00 | 11.33 | G | C |
| ATOM | 10000 | NE | ARG | G | 728 | −9.496 | 62.904 | 31.904 | 1.00 | 13.59 | G | N |
| ATOM | 10001 | CZ | ARG | G | 728 | −8.880 | 63.551 | 32.886 | 1.00 | 13.86 | G | C |
| ATOM | 10002 | NH1 | ARG | G | 728 | −7.587 | 63.819 | 32.788 | 1.00 | 12.40 | G | N |
| ATOM | 10003 | NH2 | ARG | G | 728 | −9.549 | 63.914 | 33.977 | 1.00 | 15.44 | G | N |
| ATOM | 10004 | C | ARG | G | 728 | −7.656 | 61.160 | 26.544 | 1.00 | 11.89 | G | C |
| ATOM | 10005 | O | ARG | G | 728 | −6.502 | 60.733 | 26.670 | 1.00 | 9.94 | G | O |
| ATOM | 10006 | N | TYR | G | 729 | −8.448 | 60.804 | 25.537 | 1.00 | 13.31 | G | N |
| ATOM | 10007 | CA | TYR | G | 729 | −7.983 | 59.864 | 24.528 | 1.00 | 11.97 | G | C |
| ATOM | 10008 | CB | TYR | G | 729 | −9.118 | 59.573 | 23.558 | 1.00 | 11.15 | G | C |
| ATOM | 10009 | CG | TYR | G | 729 | −8.809 | 58.462 | 22.595 | 1.00 | 16.65 | G | C |
| ATOM | 10010 | CD1 | TYR | G | 729 | −8.395 | 57.206 | 23.049 | 1.00 | 14.01 | G | C |
| ATOM | 10011 | CE1 | TYR | G | 729 | −8.133 | 56.176 | 22.153 | 1.00 | 17.74 | G | C |
| ATOM | 10012 | CD2 | TYR | G | 729 | −8.950 | 58.663 | 21.214 | 1.00 | 17.38 | G | C |
| ATOM | 10013 | CE2 | TYR | G | 729 | −8.693 | 57.647 | 20.311 | 1.00 | 19.49 | G | C |
| ATOM | 10014 | CZ | TYR | G | 729 | −8.287 | 56.407 | 20.782 | 1.00 | 22.16 | G | C |
| ATOM | 10015 | OH | TYR | G | 729 | −8.046 | 55.413 | 19.864 | 1.00 | 24.90 | G | O |
| ATOM | 10016 | C | TYR | G | 729 | −6.766 | 60.399 | 23.808 | 1.00 | 9.90 | G | C |
| ATOM | 10017 | O | TYR | G | 729 | −5.752 | 59.713 | 23.684 | 1.00 | 10.97 | G | O |
| ATOM | 10018 | N | GLU | G | 730 | −6.860 | 61.648 | 23.366 | 1.00 | 12.97 | G | N |
| ATOM | 10019 | CA | GLU | G | 730 | −5.762 | 62.287 | 22.653 | 1.00 | 12.61 | G | C |
| ATOM | 10020 | CB | GLU | G | 730 | −6.184 | 63.675 | 22.139 | 1.00 | 11.70 | G | C |
| ATOM | 10021 | CG | GLU | G | 730 | −7.398 | 63.629 | 21.224 | 1.00 | 11.91 | G | C |
| ATOM | 10022 | CD | GLU | G | 730 | −7.951 | 65.000 | 20.927 | 1.00 | 14.81 | G | C |
| ATOM | 10023 | OE1 | GLU | G | 730 | −9.020 | 65.077 | 20.285 | 1.00 | 15.61 | G | O |
| ATOM | 10024 | OE2 | GLU | G | 730 | −7.321 | 66.000 | 21.339 | 1.00 | 16.25 | G | O |
| ATOM | 10025 | C | GLU | G | 730 | −4.517 | 62.414 | 23.510 | 1.00 | 12.63 | G | C |
| ATOM | 10026 | O | GLU | G | 730 | −3.415 | 62.100 | 23.045 | 1.00 | 15.18 | G | O |
| ATOM | 10027 | N | THR | G | 731 | −4.659 | 62.856 | 24.760 | 1.00 | 11.96 | G | N |
| ATOM | 10028 | CA | THR | G | 731 | −3.452 | 62.994 | 25.566 | 1.00 | 12.57 | G | C |
| ATOM | 10029 | CB | THR | G | 731 | −3.657 | 63.992 | 26.777 | 1.00 | 13.78 | G | C |
| ATOM | 10030 | OG1 | THR | G | 731 | −3.593 | 63.305 | 28.020 | 1.00 | 21.70 | G | O |
| ATOM | 10031 | CG2 | THR | G | 731 | −4.935 | 64.728 | 26.661 | 1.00 | 2.04 | G | C |
| ATOM | 10032 | C | THR | G | 731 | −2.845 | 61.635 | 25.966 | 1.00 | 10.78 | G | C |
| ATOM | 10033 | O | THR | G | 731 | −1.635 | 61.511 | 26.117 | 1.00 | 12.54 | G | O |
| ATOM | 10034 | N | TRP | G | 732 | −3.673 | 60.602 | 26.067 | 1.00 | 10.98 | G | N |
| ATOM | 10035 | CA | TRP | G | 732 | −3.171 | 59.259 | 26.362 | 1.00 | 10.01 | G | C |
| ATOM | 10036 | CB | TRP | G | 732 | −4.343 | 58.348 | 26.691 | 1.00 | 8.39 | G | C |
| ATOM | 10037 | CG | TRP | G | 732 | −3.998 | 56.928 | 27.010 | 1.00 | 6.61 | G | C |
| ATOM | 10038 | CD2 | TRP | G | 732 | −4.860 | 55.798 | 26.853 | 1.00 | 7.81 | G | C |
| ATOM | 10039 | CE2 | TRP | G | 732 | −4.189 | 54.678 | 27.399 | 1.00 | 12.02 | G | C |
| ATOM | 10040 | CE3 | TRP | G | 732 | −6.141 | 55.624 | 26.311 | 1.00 | 10.66 | G | C |
| ATOM | 10041 | CD1 | TRP | G | 732 | −2.860 | 56.464 | 27.614 | 1.00 | 8.49 | G | C |
| ATOM | 10042 | NE1 | TRP | G | 732 | −2.965 | 55.110 | 27.853 | 1.00 | 7.89 | G | N |
| ATOM | 10043 | CZ2 | TRP | G | 732 | −4.762 | 53.396 | 27.419 | 1.00 | 12.22 | G | C |
| ATOM | 10044 | CZ3 | TRP | G | 732 | −6.708 | 54.355 | 26.331 | 1.00 | 13.83 | G | C |
| ATOM | 10045 | CH2 | TRP | G | 732 | −6.019 | 53.258 | 26.884 | 1.00 | 13.97 | G | C |
| ATOM | 10046 | C | TRP | G | 732 | −2.412 | 58.720 | 25.137 | 1.00 | 11.05 | G | C |
| ATOM | 10047 | O | TRP | G | 732 | −1.302 | 58.190 | 25.255 | 1.00 | 13.83 | G | O |
| ATOM | 10048 | N | CYS | G | 733 | −3.003 | 58.855 | 23.952 | 1.00 | 14.76 | G | N |
| ATOM | 10049 | CA | CYS | G | 733 | −2.339 | 58.373 | 22.723 | 1.00 | 14.92 | G | C |
| ATOM | 10050 | CB | CYS | G | 733 | −3.251 | 58.579 | 21.508 | 1.00 | 11.46 | G | C |
| ATOM | 10051 | SG | CYS | G | 733 | −4.677 | 57.453 | 21.462 | 1.00 | 19.94 | G | S |
| ATOM | 10052 | C | CYS | G | 733 | −1.009 | 59.113 | 22.515 | 1.00 | 14.86 | G | C |
| ATOM | 10053 | O | CYS | G | 733 | 0.003 | 58.518 | 22.138 | 1.00 | 14.72 | G | O |
| ATOM | 10054 | N | TYR | G | 734 | −1.005 | 60.413 | 22.782 | 1.00 | 13.65 | G | N |
| ATOM | 10055 | CA | TYR | G | 734 | 0.212 | 61.185 | 22.617 | 1.00 | 12.34 | G | C |
| ATOM | 10056 | CB | TYR | G | 734 | −0.044 | 62.628 | 23.028 | 1.00 | 15.57 | G | C |
| ATOM | 10057 | CG | TYR | G | 734 | 1.061 | 63.570 | 22.622 | 1.00 | 19.60 | G | C |
| ATOM | 10058 | CD1 | TYR | G | 734 | 1.012 | 64.254 | 21.415 | 1.00 | 19.30 | G | C |
| ATOM | 10059 | CE1 | TYR | G | 734 | 2.017 | 65.132 | 21.051 | 1.00 | 23.67 | G | C |
| ATOM | 10060 | CD2 | TYR | G | 734 | 2.152 | 63.787 | 23.454 | 1.00 | 24.34 | G | C |
| ATOM | 10061 | CE2 | TYR | G | 734 | 3.168 | 64.665 | 23.102 | 1.00 | 24.41 | G | C |
| ATOM | 10062 | CZ | TYR | G | 734 | 3.092 | 65.336 | 21.898 | 1.00 | 25.99 | G | C |
| ATOM | 10063 | OH | TYR | G | 734 | 4.085 | 66.226 | 21.555 | 1.00 | 29.88 | G | O |
| ATOM | 10064 | C | TYR | G | 734 | 1.374 | 60.615 | 23.426 | 1.00 | 14.40 | G | C |
| ATOM | 10065 | O | TYR | G | 734 | 2.487 | 60.451 | 22.915 | 1.00 | 13.12 | G | O |
| ATOM | 10066 | N | GLU | G | 735 | 1.122 | 60.298 | 24.694 | 1.00 | 13.52 | G | N |
| ATOM | 10067 | CA | GLU | G | 735 | 2.180 | 59.771 | 25.538 | 1.00 | 13.19 | G | C |
| ATOM | 10068 | CB | GLU | G | 735 | 1.679 | 59.625 | 26.983 | 1.00 | 15.67 | G | C |
| ATOM | 10069 | CG | GLU | G | 735 | 1.333 | 60.945 | 27.689 | 1.00 | 14.56 | G | C |
| ATOM | 10070 | CD | GLU | G | 735 | 2.487 | 61.950 | 27.700 | 1.00 | 15.36 | G | C |
| ATOM | 10071 | OE1 | GLU | G | 735 | 3.583 | 61.603 | 28.199 | 1.00 | 14.88 | G | O |
| ATOM | 10072 | OE2 | GLU | G | 735 | 2.293 | 63.091 | 27.208 | 1.00 | 12.38 | G | O |
| ATOM | 10073 | C | GLU | G | 735 | 2.712 | 58.426 | 25.029 | 1.00 | 14.61 | G | C |
| ATOM | 10074 | O | GLU | G | 735 | 3.925 | 58.176 | 25.041 | 1.00 | 16.08 | G | O |
| ATOM | 10075 | N | LEU | G | 736 | 1.808 | 57.553 | 24.599 | 1.00 | 14.38 | G | N |
| ATOM | 10076 | CA | LEU | G | 736 | 2.196 | 56.243 | 24.085 | 1.00 | 15.44 | G | C |
| ATOM | 10077 | CB | LEU | G | 736 | 0.942 | 55.395 | 23.798 | 1.00 | 13.98 | G | C |
| ATOM | 10078 | CG | LEU | G | 736 | 0.157 | 54.917 | 25.033 | 1.00 | 14.33 | G | C |
| ATOM | 10079 | CD1 | LEU | G | 736 | −1.250 | 54.475 | 24.625 | 1.00 | 7.86 | G | C |
| ATOM | 10080 | CD2 | LEU | G | 736 | 0.923 | 53.784 | 25.724 | 1.00 | 10.74 | G | C |
| ATOM | 10081 | C | LEU | G | 736 | 3.020 | 56.418 | 22.807 | 1.00 | 17.62 | G | C |
| ATOM | 10082 | O | LEU | G | 736 | 4.009 | 55.717 | 22.576 | 1.00 | 19.18 | G | O |
| ATOM | 10083 | N | ASN | G | 737 | 2.616 | 57.373 | 21.983 | 1.00 | 18.61 | G | N |
| ATOM | 10084 | CA | ASN | G | 737 | 3.309 | 57.616 | 20.732 | 1.00 | 20.48 | G | C |
| ATOM | 10085 | CB | ASN | G | 737 | 2.562 | 58.646 | 19.902 | 1.00 | 20.96 | G | C |
| ATOM | 10086 | CG | ASN | G | 737 | 3.086 | 58.721 | 18.512 | 1.00 | 23.37 | G | C |
| ATOM | 10087 | OD1 | ASN | G | 737 | 2.970 | 57.768 | 17.754 | 1.00 | 27.80 | G | O |
| ATOM | 10088 | ND2 | ASN | G | 737 | 3.687 | 59.844 | 18.165 | 1.00 | 23.43 | G | N |
| ATOM | 10089 | C | ASN | G | 737 | 4.730 | 58.091 | 20.950 | 1.00 | 22.07 | G | C |
| ATOM | 10090 | O | ASN | G | 737 | 5.627 | 57.785 | 20.158 | 1.00 | 23.00 | G | O |
| ATOM | 10091 | N | LEU | G | 738 | 4.940 | 58.846 | 22.021 | 1.00 | 19.93 | G | N |
| ATOM | 10092 | CA | LEU | G | 738 | 6.277 | 59.339 | 22.322 | 1.00 | 20.06 | G | C |
| ATOM | 10093 | CB | LEU | G | 738 | 6.280 | 60.111 | 23.636 | 1.00 | 18.80 | G | C |
| ATOM | 10094 | CG | LEU | G | 738 | 5.643 | 61.498 | 23.583 | 1.00 | 21.53 | G | C |
| ATOM | 10095 | CD1 | LEU | G | 738 | 5.684 | 62.137 | 24.981 | 1.00 | 17.94 | G | C |
| ATOM | 10096 | CD2 | LEU | G | 738 | 6.365 | 62.355 | 22.553 | 1.00 | 14.67 | G | C |
| ATOM | 10097 | C | LEU | G | 738 | 7.235 | 58.169 | 22.442 | 1.00 | 19.65 | G | C |
| ATOM | 10098 | O | LEU | G | 738 | 8.378 | 58.237 | 22.002 | 1.00 | 20.31 | G | O |
| ATOM | 10099 | N | ILE | G | 739 | 6.760 | 57.090 | 23.043 | 1.00 | 18.68 | G | N |
| ATOM | 10100 | CA | ILE | G | 739 | 7.591 | 55.920 | 23.225 | 1.00 | 18.09 | G | C |
| ATOM | 10101 | CB | ILE | G | 739 | 6.929 | 54.925 | 24.195 | 1.00 | 19.51 | G | C |
| ATOM | 10102 | CG2 | ILE | G | 739 | 7.706 | 53.595 | 24.195 | 1.00 | 13.88 | G | C |
| ATOM | 10103 | CG1 | ILE | G | 739 | 6.860 | 55.546 | 25.598 | 1.00 | 19.02 | G | C |
| ATOM | 10104 | CD1 | ILE | G | 739 | 5.722 | 54.996 | 26.449 | 1.00 | 19.46 | G | C |
| ATOM | 10105 | C | ILE | G | 739 | 7.836 | 55.230 | 21.893 | 1.00 | 19.36 | G | C |
| ATOM | 10106 | O | ILE | G | 739 | 8.941 | 54.783 | 21.614 | 1.00 | 18.81 | G | O |
| ATOM | 10107 | N | ALA | G | 740 | 6.795 | 55.139 | 21.080 | 1.00 | 20.33 | G | N |
| ATOM | 10108 | CA | ALA | G | 740 | 6.906 | 54.501 | 19.780 | 1.00 | 20.82 | G | C |
| ATOM | 10109 | CB | ALA | G | 740 | 5.544 | 54.501 | 19.080 | 1.00 | 21.28 | G | C |
| ATOM | 10110 | C | ALA | G | 740 | 7.928 | 55.250 | 18.940 | 1.00 | 21.52 | G | C |
| ATOM | 10111 | O | ALA | G | 740 | 8.801 | 54.635 | 18.330 | 1.00 | 21.19 | G | O |
| ATOM | 10112 | N | GLU | G | 741 | 7.830 | 56.577 | 18.920 | 1.00 | 19.46 | G | N |
| ATOM | 10113 | CA | GLU | G | 741 | 8.750 | 57.380 | 18.127 | 1.00 | 22.01 | G | C |
| ATOM | 10114 | CB | GLU | G | 741 | 8.338 | 58.849 | 18.160 | 1.00 | 22.59 | G | C |
| ATOM | 10115 | CG | GLU | G | 741 | 6.937 | 59.099 | 17.646 | 1.00 | 33.17 | G | C |
| ATOM | 10116 | CD | GLU | G | 741 | 6.873 | 59.208 | 16.137 | 1.00 | 37.03 | G | C |
| ATOM | 10117 | OE1 | GLU | G | 741 | 5.830 | 58.824 | 15.558 | 1.00 | 40.10 | G | O |
| ATOM | 10118 | OE2 | GLU | G | 741 | 7.868 | 59.678 | 15.531 | 1.00 | 41.93 | G | O |
| ATOM | 10119 | C | GLU | G | 741 | 10.185 | 57.238 | 18.625 | 1.00 | 23.58 | G | C |
| ATOM | 10120 | O | GLU | G | 741 | 11.133 | 57.208 | 17.844 | 1.00 | 23.01 | G | O |
| ATOM | 10121 | N | GLY | G | 742 | 10.353 | 57.151 | 19.935 | 1.00 | 22.79 | G | N |
| ATOM | 10122 | CA | GLY | G | 742 | 11.690 | 57.006 | 20.460 | 1.00 | 23.03 | G | C |
| ATOM | 10123 | C | GLY | G | 742 | 12.321 | 55.701 | 20.016 | 1.00 | 25.59 | G | C |
| ATOM | 10124 | O | GLY | G | 742 | 13.535 | 55.560 | 20.043 | 1.00 | 28.18 | G | O |
| ATOM | 10125 | N | LEU | G | 743 | 11.496 | 54.748 | 19.596 | 1.00 | 26.93 | G | N |
| ATOM | 10126 | CA | LEU | G | 743 | 11.960 | 53.434 | 19.165 | 1.00 | 27.44 | G | C |
| ATOM | 10127 | CB | LEU | G | 743 | 11.005 | 52.361 | 19.687 | 1.00 | 24.22 | G | C |
| ATOM | 10128 | CG | LEU | G | 743 | 11.306 | 51.643 | 21.006 | 1.00 | 29.61 | G | C |
| ATOM | 10129 | CD1 | LEU | G | 743 | 12.252 | 52.472 | 21.872 | 1.00 | 29.88 | G | C |
| ATOM | 10130 | CD2 | LEU | G | 743 | 9.993 | 51.368 | 21.738 | 1.00 | 25.19 | G | C |
| ATOM | 10131 | C | LEU | G | 743 | 12.043 | 53.293 | 17.648 | 1.00 | 31.71 | G | C |
| ATOM | 10132 | O | LEU | G | 743 | 12.690 | 52.378 | 17.141 | 1.00 | 33.69 | G | O |
| ATOM | 10133 | N | LYS | G | 744 | 11.373 | 54.196 | 16.939 | 1.00 | 34.36 | G | N |
| ATOM | 10134 | CA | LYS | G | 744 | 11.302 | 54.197 | 15.477 | 1.00 | 37.49 | G | C |
| ATOM | 10135 | CB | LYS | G | 744 | 10.516 | 55.418 | 15.013 | 1.00 | 35.07 | G | C |
| ATOM | 10136 | CG | LYS | G | 744 | 9.235 | 55.103 | 14.324 | 1.00 | 32.71 | G | C |
| ATOM | 10137 | CD | LYS | G | 744 | 8.990 | 56.136 | 13.268 | 1.00 | 34.81 | G | C |
| ATOM | 10138 | CE | LYS | G | 744 | 7.626 | 56.745 | 13.410 | 1.00 | 35.75 | G | C |
| ATOM | 10139 | NZ | LYS | G | 744 | 7.208 | 57.276 | 12.091 | 1.00 | 37.09 | G | N |
| ATOM | 10140 | C | LYS | G | 744 | 12.619 | 54.161 | 14.713 | 1.00 | 40.95 | G | C |
| ATOM | 10141 | O | LYS | G | 744 | 13.593 | 54.816 | 15.090 | 1.00 | 41.20 | G | O |
| ATOM | 10142 | N | SER | G | 745 | 12.625 | 53.396 | 13.623 | 1.00 | 46.10 | G | N |
| ATOM | 10143 | CA | SER | G | 745 | 13.795 | 53.264 | 12.752 | 1.00 | 52.26 | G | C |
| ATOM | 10144 | CB | SER | G | 745 | 14.931 | 52.544 | 13.480 | 1.00 | 53.62 | G | C |
| ATOM | 10145 | OG | SER | G | 745 | 16.172 | 53.153 | 13.178 | 1.00 | 56.29 | G | O |
| ATOM | 10146 | C | SER | G | 745 | 13.450 | 52.503 | 11.465 | 1.00 | 55.42 | G | C |
| ATOM | 10147 | O | SER | G | 745 | 13.820 | 51.304 | 11.361 | 1.00 | 57.88 | G | O |
| ATOM | 10148 | OT | SER | G | 745 | 12.815 | 53.122 | 10.574 | 1.00 | 56.30 | G | O |
| ATOM | 10149 | ZN | ZN | Y | 895 | 25.898 | 63.834 | 54.211 | 1.00 | 14.03 | Y | |
| ATOM | 10150 | ZN | ZN | Z | 896 | −10.123 | 48.415 | 52.360 | 1.00 | 17.02 | Z | |
| ATOM | 10151 | OW | HOH | W | 96 | 2.967 | 50.679 | 48.947 | 1.00 | 18.78 | W | O |
| ATOM | 10152 | OW | HOH | W | 97 | 15.078 | 55.875 | 57.495 | 1.00 | 14.43 | W | O |
| ATOM | 10153 | OW | HOH | W | 98 | 12.697 | 60.944 | 53.256 | 1.00 | 31.73 | W | O |
| ATOM | 10154 | OW | HOH | W | 99 | 15.368 | 51.021 | 53.671 | 1.00 | 29.98 | W | O |
| ATOM | 10155 | OW | HOH | W | 100 | 6.199 | 47.166 | 53.074 | 1.00 | 33.34 | W | O |
| ATOM | 10156 | OW | HOH | W | 101 | 11.852 | 58.323 | 53.365 | 1.00 | 29.21 | W | O |
| ATOM | 10157 | OW | HOH | W | 102 | 3.937 | 54.692 | 53.254 | 1.00 | 28.79 | W | O |
| ATOM | 10158 | OW | HOH | W | 103 | 10.677 | 55.317 | 55.973 | 1.00 | 42.20 | W | O |
| ATOM | 10159 | OW | HOH | W | 104 | −27.334 | 66.640 | 31.829 | 1.00 | 8.14 | W | O |
| ATOM | 10160 | OW | HOH | W | 105 | 15.630 | 71.112 | 71.282 | 1.00 | 8.04 | W | O |
| ATOM | 10161 | OW | HOH | W | 106 | −17.468 | 55.319 | 42.651 | 1.00 | 11.96 | W | O |
| ATOM | 10162 | OW | HOH | W | 107 | 19.103 | 76.038 | 57.016 | 1.00 | 10.32 | W | O |
| ATOM | 10163 | OW | HOH | W | 108 | −21.578 | 46.036 | 42.064 | 1.00 | 10.18 | W | O |
| ATOM | 10164 | OW | HOH | W | 109 | 22.544 | 71.730 | 53.905 | 1.00 | 8.44 | W | O |
| ATOM | 10165 | OW | HOH | W | 110 | 35.093 | 65.495 | 64.390 | 1.00 | 16.20 | W | O |
| ATOM | 10166 | OW | HOH | W | 111 | −22.112 | 60.161 | 23.355 | 1.00 | 15.28 | W | O |
| ATOM | 10167 | OW | HOH | W | 112 | −17.844 | 42.922 | 42.265 | 1.00 | 12.38 | W | O |
| ATOM | 10168 | OW | HOH | W | 113 | −8.505 | 60.904 | 35.216 | 1.00 | 10.12 | W | O |
| ATOM | 10169 | OW | HOH | W | 114 | 19.352 | 65.825 | 52.028 | 1.00 | 10.91 | W | O |
| ATOM | 10170 | OW | HOH | W | 115 | 21.384 | 59.242 | 54.683 | 1.00 | 12.32 | W | O |
| ATOM | 10171 | OW | HOH | W | 116 | −18.441 | 74.733 | 48.908 | 1.00 | 14.76 | W | O |
| ATOM | 10172 | OW | HOH | W | 117 | 11.783 | 70.552 | 75.613 | 1.00 | 16.21 | W | O |
| ATOM | 10173 | OW | HOH | W | 118 | 52.372 | 54.088 | 58.694 | 1.00 | 14.36 | W | O |
| ATOM | 10174 | OW | HOH | W | 119 | 26.707 | 63.603 | 63.140 | 1.00 | 8.31 | W | O |
| ATOM | 10175 | OW | HOH | W | 120 | 35.558 | 70.382 | 64.698 | 1.00 | 8.10 | W | O |
| ATOM | 10176 | OW | HOH | W | 121 | 14.379 | 70.967 | 53.856 | 1.00 | 15.15 | W | O |
| ATOM | 10177 | OW | HOH | W | 122 | −9.271 | 45.899 | 46.567 | 1.00 | 10.12 | W | O |
| ATOM | 10178 | OW | HOH | W | 123 | 13.759 | 84.960 | 73.175 | 1.00 | 26.19 | W | O |
| ATOM | 10179 | OW | HOH | W | 124 | 8.837 | 73.580 | 83.658 | 1.00 | 17.10 | W | O |
| ATOM | 10180 | OW | HOH | W | 125 | −4.402 | 54.667 | 36.009 | 1.00 | 11.86 | W | O |
| ATOM | 10181 | OW | HOH | W | 126 | 1.402 | 68.680 | 21.627 | 1.00 | 13.79 | W | O |
| ATOM | 10182 | OW | HOH | W | 127 | −14.370 | 61.855 | 49.724 | 1.00 | 12.92 | W | O |
| ATOM | 10183 | OW | HOH | W | 128 | 32.642 | 69.583 | 82.451 | 1.00 | 18.02 | W | O |
| ATOM | 10184 | OW | HOH | W | 129 | 6.140 | 58.786 | 26.832 | 1.00 | 18.45 | W | O |
| ATOM | 10185 | OW | HOH | W | 130 | −16.581 | 35.960 | 38.113 | 1.00 | 14.73 | W | O |
| ATOM | 10186 | OW | HOH | W | 131 | 35.761 | 85.732 | 71.836 | 1.00 | 21.86 | W | O |
| ATOM | 10187 | OW | HOH | W | 132 | −28.815 | 51.230 | 38.551 | 1.00 | 17.13 | W | O |
| ATOM | 10188 | OW | HOH | W | 133 | 25.932 | 73.624 | 64.086 | 1.00 | 17.66 | W | O |
| ATOM | 10189 | OW | HOH | W | 134 | −7.596 | 61.886 | 52.676 | 1.00 | 12.08 | W | O |
| ATOM | 10190 | OW | HOH | W | 135 | −6.958 | 59.266 | 30.977 | 1.00 | 10.85 | W | O |
| ATOM | 10191 | OW | HOH | W | 136 | 17.451 | 63.887 | 70.465 | 1.00 | 9.03 | W | O |
| ATOM | 10192 | OW | HOH | W | 137 | 28.244 | 77.532 | 71.624 | 1.00 | 15.16 | W | O |
| ATOM | 10193 | OW | HOH | W | 138 | −12.259 | 78.898 | 33.273 | 1.00 | 30.07 | W | O |
| ATOM | 10194 | OW | HOH | W | 139 | −6.099 | 46.573 | 33.828 | 1.00 | 19.36 | W | O |
| ATOM | 10195 | OW | HOH | W | 140 | −13.413 | 56.393 | 52.588 | 1.00 | 5.38 | W | O |
| ATOM | 10196 | OW | HOH | W | 141 | −22.006 | 39.030 | 42.479 | 1.00 | 17.55 | W | O |
| ATOM | 10197 | OW | HOH | W | 142 | −13.144 | 68.297 | 18.477 | 1.00 | 14.72 | W | O |
| ATOM | 10198 | OW | HOH | W | 143 | −5.390 | 67.267 | 22.969 | 1.00 | 11.97 | W | O |
| ATOM | 10199 | OW | HOH | W | 144 | 10.290 | 55.605 | 40.299 | 1.00 | 12.62 | W | O |
| ATOM | 10200 | OW | HOH | W | 145 | −21.756 | 56.047 | 35.118 | 1.00 | 15.46 | W | O |
| ATOM | 10201 | OW | HOH | W | 146 | −4.003 | 37.477 | 50.604 | 1.00 | 10.57 | W | O |
| ATOM | 10202 | OW | HOH | W | 147 | −17.240 | 71.673 | 33.443 | 1.00 | 12.30 | W | O |
| ATOM | 10203 | OW | HOH | W | 148 | −21.742 | 22.615 | 48.272 | 1.00 | 8.65 | W | O |
| ATOM | 10204 | OW | HOH | W | 149 | −6.861 | 54.611 | 54.649 | 1.00 | 10.36 | W | O |
| ATOM | 10205 | OW | HOH | W | 150 | −17.199 | 39.171 | 58.479 | 1.00 | 19.72 | W | O |
| ATOM | 10206 | OW | HOH | W | 151 | −0.085 | 64.096 | 26.343 | 1.00 | 8.30 | W | O |
| ATOM | 10207 | OW | HOH | W | 152 | −8.692 | 43.188 | 27.993 | 1.00 | 23.56 | W | O |
| ATOM | 10208 | OW | HOH | W | 153 | 27.085 | 61.615 | 60.095 | 1.00 | 16.91 | W | O |
| ATOM | 10209 | OW | HOH | W | 154 | 31.582 | 62.725 | 50.060 | 1.00 | 21.48 | W | O |
| ATOM | 10210 | OW | HOH | W | 155 | 7.217 | 59.167 | 79.512 | 1.00 | 14.32 | W | O |
| ATOM | 10211 | OW | HOH | W | 156 | −29.374 | 31.227 | 39.099 | 1.00 | 20.43 | W | O |
| ATOM | 10212 | OW | HOH | W | 157 | 29.295 | 75.616 | 39.592 | 1.00 | 19.82 | W | O |
| ATOM | 10213 | OW | HOH | W | 158 | −10.474 | 47.832 | 43.646 | 1.00 | 9.21 | W | O |
| ATOM | 10214 | OW | HOH | W | 159 | 37.529 | 72.123 | 65.418 | 1.00 | 13.05 | W | O |
| ATOM | 10215 | OW | HOH | W | 160 | 43.919 | 66.262 | 44.512 | 1.00 | 13.43 | W | O |
| ATOM | 10216 | OW | HOH | W | 161 | 28.753 | 76.295 | 45.996 | 1.00 | 19.73 | W | O |
| ATOM | 10217 | OW | HOH | W | 162 | 51.509 | 55.360 | 54.060 | 1.00 | 21.46 | W | O |
| ATOM | 10218 | OW | HOH | W | 163 | 8.400 | 81.685 | 57.569 | 1.00 | 19.28 | W | O |
| ATOM | 10219 | OW | HOH | W | 164 | 18.701 | 67.012 | 57.584 | 1.00 | 16.02 | W | O |
| ATOM | 10220 | OW | HOH | W | 165 | −31.811 | 37.710 | 61.624 | 1.00 | 21.61 | W | O |
| ATOM | 10221 | OW | HOH | W | 166 | 6.297 | 53.980 | 66.212 | 1.00 | 15.94 | W | O |
| ATOM | 10222 | OW | HOH | W | 167 | 3.151 | 69.388 | 85.101 | 1.00 | 21.34 | W | O |
| ATOM | 10223 | OW | HOH | W | 168 | 4.645 | 63.949 | 40.103 | 1.00 | 32.28 | W | O |
| ATOM | 10224 | OW | HOH | W | 169 | −3.966 | 65.784 | 31.720 | 1.00 | 22.68 | W | O |
| ATOM | 10225 | OW | HOH | W | 170 | 22.198 | 73.790 | 74.708 | 1.00 | 12.30 | W | O |
| ATOM | 10226 | OW | HOH | W | 171 | 34.954 | 45.014 | 74.822 | 1.00 | 34.82 | W | O |
| ATOM | 10227 | OW | HOH | W | 172 | 19.670 | 56.775 | 90.866 | 1.00 | 25.89 | W | O |
| ATOM | 10228 | OW | HOH | W | 173 | −24.262 | 45.751 | 41.348 | 1.00 | 13.40 | W | O |
| ATOM | 10229 | OW | HOH | W | 174 | 47.695 | 56.621 | 25.265 | 1.00 | 40.94 | W | O |
| ATOM | 10230 | OW | HOH | W | 175 | −24.212 | 39.616 | 30.689 | 1.00 | 14.92 | W | O |
| ATOM | 10231 | OW | HOH | W | 176 | 42.734 | 69.560 | 61.971 | 1.00 | 20.79 | W | O |
| ATOM | 10232 | OW | HOH | W | 177 | 39.424 | 59.877 | 68.626 | 1.00 | 12.09 | W | O |
| ATOM | 10233 | OW | HOH | W | 178 | 8.841 | 71.331 | 74.954 | 1.00 | 15.39 | W | O |
| ATOM | 10234 | OW | HOH | W | 179 | 19.092 | 71.818 | 80.312 | 1.00 | 14.76 | W | O |
| ATOM | 10235 | OW | HOH | W | 180 | −28.380 | 52.770 | 45.177 | 1.00 | 24.13 | W | O |
| ATOM | 10236 | OW | HOH | W | 181 | 25.089 | 80.412 | 83.182 | 1.00 | 20.73 | W | O |
| ATOM | 10237 | OW | HOH | W | 182 | 40.709 | 44.145 | 48.184 | 1.00 | 20.44 | W | O |
| ATOM | 10238 | OW | HOH | W | 183 | 18.662 | 69.045 | 73.736 | 1.00 | 21.84 | W | O |
| ATOM | 10239 | OW | HOH | W | 184 | 13.378 | 79.577 | 88.068 | 1.00 | 22.10 | W | O |
| ATOM | 10240 | OW | HOH | W | 185 | 33.184 | 76.581 | 52.007 | 1.00 | 37.26 | W | O |
| ATOM | 10241 | OW | HOH | W | 186 | −24.867 | 67.145 | 24.872 | 1.00 | 17.27 | W | O |
| ATOM | 10242 | OW | HOH | W | 187 | 45.245 | 63.331 | 38.115 | 1.00 | 28.20 | W | O |
| ATOM | 10243 | OW | HOH | W | 188 | −5.305 | 63.209 | 30.923 | 1.00 | 15.98 | W | O |
| ATOM | 10244 | OW | HOH | W | 189 | −1.072 | 46.722 | 68.742 | 1.00 | 32.07 | W | O |
| ATOM | 10245 | OW | HOH | W | 190 | 11.532 | 75.187 | 48.802 | 1.00 | 23.83 | W | O |
| ATOM | 10246 | OW | HOH | W | 191 | −25.624 | 40.242 | 45.176 | 1.00 | 14.50 | W | O |
| ATOM | 10247 | OW | HOH | W | 192 | −32.246 | 54.134 | 33.180 | 1.00 | 32.39 | W | O |
| ATOM | 10248 | OW | HOH | W | 193 | −19.991 | 54.856 | 27.900 | 1.00 | 15.83 | W | O |
| ATOM | 10249 | OW | HOH | W | 194 | 28.761 | 68.722 | 36.772 | 1.00 | 24.74 | W | O |
| ATOM | 10250 | OW | HOH | W | 195 | 7.547 | 67.212 | 80.327 | 1.00 | 12.86 | W | O |
| ATOM | 10251 | OW | HOH | W | 196 | 7.571 | 77.433 | 80.892 | 1.00 | 15.93 | W | O |
| ATOM | 10252 | OW | HOH | W | 197 | 22.177 | 87.372 | 81.834 | 1.00 | 19.83 | W | O |
| ATOM | 10253 | OW | HOH | W | 198 | 34.320 | 63.481 | 51.262 | 1.00 | 16.96 | W | O |
| ATOM | 10254 | OW | HOH | W | 199 | 25.354 | 74.447 | 38.457 | 1.00 | 29.71 | W | O |
| ATOM | 10255 | OW | HOH | W | 200 | −26.425 | 51.355 | 56.553 | 1.00 | 16.44 | W | O |
| ATOM | 10256 | OW | HOH | W | 201 | −0.225 | 68.290 | 23.403 | 1.00 | 21.86 | W | O |
| ATOM | 10257 | OW | HOH | W | 202 | −10.932 | 37.096 | 34.847 | 1.00 | 14.74 | W | O |
| ATOM | 10258 | OW | HOH | W | 203 | −19.105 | 47.355 | 24.229 | 1.00 | 20.65 | W | O |
| ATOM | 10259 | OW | HOH | W | 204 | −3.728 | 52.280 | 71.587 | 1.00 | 27.37 | W | O |
| ATOM | 10260 | OW | HOH | W | 205 | 24.395 | 59.505 | 72.901 | 1.00 | 19.64 | W | O |
| ATOM | 10261 | OW | HOH | W | 206 | 21.221 | 68.818 | 80.002 | 1.00 | 21.74 | W | O |
| ATOM | 10262 | OW | HOH | W | 207 | 20.510 | 55.549 | 37.333 | 1.00 | 32.61 | W | O |
| ATOM | 10263 | OW | HOH | W | 208 | 33.152 | 74.795 | 55.318 | 1.00 | 27.55 | W | O |
| ATOM | 10264 | OW | HOH | W | 209 | 35.017 | 37.479 | 58.269 | 1.00 | 17.44 | W | O |
| ATOM | 10265 | OW | HOH | W | 210 | 29.415 | 80.601 | 31.418 | 1.00 | 21.97 | W | O |
| ATOM | 10266 | OW | HOH | W | 211 | 36.903 | 79.091 | 68.321 | 1.00 | 18.24 | W | O |
| ATOM | 10267 | OW | HOH | W | 212 | −29.336 | 25.492 | 49.863 | 1.00 | 22.56 | W | O |
| ATOM | 10268 | OW | HOH | W | 213 | 40.702 | 55.873 | 50.476 | 1.00 | 14.27 | W | O |
| ATOM | 10269 | OW | HOH | W | 214 | 12.389 | 87.793 | 57.749 | 1.00 | 24.18 | W | O |
| ATOM | 10270 | OW | HOH | W | 215 | −21.091 | 55.021 | 60.742 | 1.00 | 13.33 | W | O |
| ATOM | 10271 | OW | HOH | W | 216 | 9.247 | 71.708 | 61.523 | 1.00 | 10.93 | W | O |
| ATOM | 10272 | OW | HOH | W | 217 | 30.188 | 89.466 | 68.858 | 1.00 | 27.66 | W | O |
| ATOM | 10273 | OW | HOH | W | 218 | 30.347 | 78.601 | 72.233 | 1.00 | 15.25 | W | O |
| ATOM | 10274 | OW | HOH | W | 219 | −0.848 | 66.047 | 24.402 | 1.00 | 20.24 | W | O |
| ATOM | 10275 | OW | HOH | W | 220 | −5.428 | 69.627 | 24.516 | 1.00 | 16.34 | W | O |
| ATOM | 10276 | OW | HOH | W | 221 | −10.911 | 48.435 | 55.939 | 1.00 | 27.19 | W | O |
| ATOM | 10277 | OW | HOH | W | 222 | 21.752 | 49.128 | 80.145 | 1.00 | 14.92 | W | O |
| ATOM | 10278 | OW | HOH | W | 223 | −8.338 | 50.109 | 31.764 | 1.00 | 18.48 | W | O |
| ATOM | 10279 | OW | HOH | W | 224 | −21.211 | 30.155 | 58.331 | 1.00 | 27.02 | W | O |
| ATOM | 10280 | OW | HOH | W | 225 | −9.249 | 57.251 | 33.007 | 1.00 | 22.87 | W | O |
| ATOM | 10281 | OW | HOH | W | 226 | 33.370 | 61.918 | 66.266 | 1.00 | 16.25 | W | O |
| ATOM | 10282 | OW | HOH | W | 227 | 47.402 | 56.019 | 67.430 | 1.00 | 21.12 | W | O |
| ATOM | 10283 | OW | HOH | W | 228 | −33.250 | 56.751 | 34.540 | 1.00 | 25.50 | W | O |
| ATOM | 10284 | OW | HOH | W | 229 | −35.702 | 47.930 | 48.379 | 1.00 | 27.10 | W | O |
| ATOM | 10285 | OW | HOH | W | 230 | −7.311 | 55.702 | 48.806 | 1.00 | 16.26 | W | O |
| ATOM | 10286 | OW | HOH | W | 231 | 46.425 | 59.375 | 36.146 | 1.00 | 30.08 | W | O |
| ATOM | 10287 | OW | HOH | W | 232 | −33.660 | 38.594 | 64.351 | 1.00 | 24.33 | W | O |
| ATOM | 10288 | OW | HOH | W | 233 | 16.531 | 37.171 | 68.296 | 1.00 | 25.49 | W | O |
| ATOM | 10289 | OW | HOH | W | 234 | −21.441 | 53.346 | 24.188 | 1.00 | 22.36 | W | O |
| ATOM | 10290 | OW | HOH | W | 235 | −5.431 | 60.915 | 29.493 | 1.00 | 10.06 | W | O |
| ATOM | 10291 | OW | HOH | W | 236 | −31.633 | 50.191 | 36.839 | 1.00 | 35.56 | W | O |
| ATOM | 10292 | OW | HOH | W | 237 | −19.185 | 31.306 | 56.842 | 1.00 | 13.83 | W | O |
| ATOM | 10293 | OW | HOH | W | 238 | 35.548 | 82.385 | 41.600 | 1.00 | 24.54 | W | O |
| ATOM | 10294 | OW | HOH | W | 239 | −20.811 | 54.465 | 67.061 | 1.00 | 15.36 | W | O |
| ATOM | 10295 | OW | HOH | W | 240 | 6.590 | 71.573 | 67.846 | 1.00 | 17.11 | W | O |
| ATOM | 10296 | OW | HOH | W | 241 | 22.109 | 58.778 | 73.929 | 1.00 | 11.60 | W | O |
| ATOM | 10297 | OW | HOH | W | 242 | 35.167 | 77.566 | 50.318 | 1.00 | 23.87 | W | O |
| ATOM | 10298 | OW | HOH | W | 243 | 4.529 | 70.148 | 83.109 | 1.00 | 21.13 | W | O |
| ATOM | 10299 | OW | HOH | W | 244 | −2.591 | 67.794 | 38.763 | 1.00 | 13.45 | W | O |
| ATOM | 10300 | OW | HOH | W | 245 | −7.607 | 70.835 | 25.495 | 1.00 | 14.30 | W | O |
| ATOM | 10301 | OW | HOH | W | 246 | −21.277 | 39.066 | 31.788 | 1.00 | 24.61 | W | O |
| ATOM | 10302 | OW | HOH | W | 247 | 40.731 | 65.711 | 64.110 | 1.00 | 29.98 | W | O |
| ATOM | 10303 | OW | HOH | W | 248 | −27.555 | 51.436 | 24.149 | 1.00 | 34.70 | W | O |
| ATOM | 10304 | OW | HOH | W | 249 | −23.765 | 42.109 | 37.749 | 1.00 | 23.56 | W | O |
| ATOM | 10305 | OW | HOH | W | 250 | −14.529 | 32.313 | 55.952 | 1.00 | 13.81 | W | O |
| ATOM | 10306 | OW | HOH | W | 251 | −29.486 | 34.606 | 32.955 | 1.00 | 27.16 | W | O |
| ATOM | 10307 | OW | HOH | W | 252 | −21.455 | 32.749 | 68.526 | 1.00 | 25.82 | W | O |
| ATOM | 10308 | OW | HOH | W | 253 | 8.780 | 30.499 | 46.795 | 1.00 | 28.37 | W | O |
| ATOM | 10309 | OW | HOH | W | 254 | 39.807 | 62.398 | 69.472 | 1.00 | 24.47 | W | O |
| ATOM | 10310 | OW | HOH | W | 255 | 16.545 | 75.853 | 70.012 | 1.00 | 36.10 | W | O |
| ATOM | 10311 | OW | HOH | W | 256 | −21.231 | 58.753 | 34.556 | 1.00 | 10.88 | W | O |
| ATOM | 10312 | OW | HOH | W | 257 | −24.609 | 55.856 | 48.311 | 1.00 | 23.31 | W | O |
| ATOM | 10313 | OW | HOH | W | 258 | 13.222 | 82.598 | 72.789 | 1.00 | 16.61 | W | O |
| ATOM | 10314 | OW | HOH | W | 259 | 15.667 | 69.012 | 75.624 | 1.00 | 13.01 | W | O |
| ATOM | 10315 | OW | HOH | W | 260 | 49.230 | 59.563 | 49.756 | 1.00 | 17.94 | W | O |
| ATOM | 10316 | OW | HOH | W | 261 | −15.723 | 30.180 | 30.160 | 1.00 | 26.01 | W | O |
| ATOM | 10317 | OW | HOH | W | 262 | 43.419 | 56.146 | 50.603 | 1.00 | 16.76 | W | O |
| ATOM | 10318 | OW | HOH | W | 263 | 30.441 | 79.629 | 58.350 | 1.00 | 29.81 | W | O |
| ATOM | 10319 | OW | HOH | W | 264 | −0.262 | 39.081 | 59.736 | 1.00 | 21.91 | W | O |
| ATOM | 10320 | OW | HOH | W | 265 | −27.838 | 59.225 | 42.281 | 1.00 | 30.21 | W | O |
| ATOM | 10321 | OW | HOH | W | 266 | −15.473 | 50.057 | 70.006 | 1.00 | 25.38 | W | O |
| ATOM | 10322 | OW | HOH | W | 267 | −24.168 | 55.338 | 34.299 | 1.00 | 11.08 | W | O |
| ATOM | 10323 | OW | HOH | W | 268 | −20.242 | 35.861 | 70.543 | 1.00 | 23.10 | W | O |
| ATOM | 10324 | OW | HOH | W | 269 | −17.367 | 74.249 | 35.175 | 1.00 | 26.91 | W | O |
| ATOM | 10325 | OW | HOH | W | 270 | 24.426 | 91.260 | 75.443 | 1.00 | 17.29 | W | O |
| ATOM | 10326 | OW | HOH | W | 271 | 28.855 | 58.822 | 78.354 | 1.00 | 28.88 | W | O |
| ATOM | 10327 | OW | HOH | W | 272 | 27.865 | 75.115 | 78.727 | 1.00 | 12.35 | W | O |
| ATOM | 10328 | OW | HOH | W | 273 | 6.425 | 68.927 | 82.204 | 1.00 | 17.79 | W | O |
| ATOM | 10329 | OW | HOH | W | 274 | −22.613 | 50.165 | 51.382 | 1.00 | 20.66 | W | O |
| ATOM | 10330 | OW | HOH | W | 275 | −15.216 | 24.432 | 51.991 | 1.00 | 23.53 | W | O |
| ATOM | 10331 | OW | HOH | W | 276 | −16.925 | 38.376 | 55.676 | 1.00 | 20.18 | W | O |
| ATOM | 10332 | OW | HOH | W | 277 | 29.417 | 52.045 | 55.925 | 1.00 | 16.98 | W | O |
| ATOM | 10333 | OW | HOH | W | 278 | 23.931 | 90.582 | 61.684 | 1.00 | 17.06 | W | O |
| ATOM | 10334 | OW | HOH | W | 279 | −24.115 | 37.037 | 62.019 | 1.00 | 22.09 | W | O |
| ATOM | 10335 | OW | HOH | W | 280 | −20.199 | 58.116 | 20.966 | 1.00 | 24.43 | W | O |
| ATOM | 10336 | OW | HOH | W | 281 | 24.335 | 71.502 | 80.780 | 1.00 | 30.24 | W | O |
| ATOM | 10337 | OW | HOH | W | 282 | 41.894 | 68.142 | 76.210 | 1.00 | 21.53 | W | O |
| ATOM | 10338 | OW | HOH | W | 283 | 2.056 | 67.433 | 86.781 | 1.00 | 34.93 | W | O |
| ATOM | 10339 | OW | HOH | W | 284 | −28.055 | 51.451 | 54.175 | 1.00 | 25.40 | W | O |
| ATOM | 10340 | OW | HOH | W | 285 | −14.026 | 17.114 | 44.504 | 1.00 | 24.41 | W | O |
| ATOM | 10341 | OW | HOH | W | 286 | −9.866 | 69.854 | 38.686 | 1.00 | 31.31 | W | O |
| ATOM | 10342 | OW | HOH | W | 287 | −24.807 | 51.761 | 54.347 | 1.00 | 33.23 | W | O |
| ATOM | 10343 | OW | HOH | W | 288 | −13.105 | 73.251 | 38.493 | 1.00 | 38.55 | W | O |
| ATOM | 10344 | OW | HOH | W | 289 | −24.726 | 38.607 | 42.977 | 1.00 | 19.51 | W | O |
| ATOM | 10345 | OW | HOH | W | 290 | 37.733 | 85.833 | 73.274 | 1.00 | 33.44 | W | O |
| ATOM | 10346 | OW | HOH | W | 291 | 44.480 | 58.580 | 49.938 | 1.00 | 19.22 | W | O |
| ATOM | 10347 | OW | HOH | W | 292 | 25.782 | 81.788 | 37.826 | 1.00 | 23.48 | W | O |
| ATOM | 10348 | OW | HOH | W | 293 | −2.536 | 49.254 | 55.570 | 1.00 | 23.99 | W | O |
| ATOM | 10349 | OW | HOH | W | 294 | −24.942 | 70.975 | 23.190 | 1.00 | 31.28 | W | O |
| ATOM | 10350 | OW | HOH | W | 295 | −16.326 | 41.343 | 61.608 | 1.00 | 18.28 | W | O |
| ATOM | 10351 | OW | HOH | W | 296 | 40.070 | 69.373 | 69.087 | 1.00 | 18.72 | W | O |
| ATOM | 10352 | OW | HOH | W | 297 | −29.931 | 23.684 | 52.192 | 1.00 | 35.88 | W | O |
| ATOM | 10353 | OW | HOH | W | 298 | 21.472 | 42.076 | 54.642 | 1.00 | 22.72 | W | O |
| ATOM | 10354 | OW | HOH | W | 299 | −24.797 | 59.681 | 22.423 | 1.00 | 39.13 | W | O |
| ATOM | 10355 | OW | HOH | W | 300 | −15.889 | 42.025 | 55.239 | 1.00 | 15.73 | W | O |
| ATOM | 10356 | OW | HOH | W | 301 | 7.565 | 80.330 | 55.164 | 1.00 | 34.69 | W | O |
| ATOM | 10357 | OW | HOH | W | 302 | −16.936 | 36.609 | 58.716 | 1.00 | 24.29 | W | O |
| ATOM | 10358 | OW | HOH | W | 303 | −14.944 | 57.876 | 31.989 | 1.00 | 16.40 | W | O |
| ATOM | 10359 | OW | HOH | W | 304 | 37.456 | 77.333 | 27.476 | 1.00 | 35.46 | W | O |
| ATOM | 10360 | OW | HOH | W | 305 | 23.038 | 63.610 | 74.859 | 1.00 | 21.03 | W | O |
| ATOM | 10361 | OW | HOH | W | 306 | 39.487 | 60.590 | 48.116 | 1.00 | 16.15 | W | O |
| ATOM | 10362 | OW | HOH | W | 307 | 37.084 | 83.513 | 73.320 | 1.00 | 25.94 | W | O |
| ATOM | 10363 | OW | HOH | W | 308 | 30.099 | 64.739 | 49.179 | 1.00 | 29.96 | W | O |
| ATOM | 10364 | OW | HOH | W | 309 | −8.407 | 27.861 | 29.257 | 1.00 | 27.28 | W | O |
| ATOM | 10365 | OW | HOH | W | 310 | 8.718 | 36.580 | 51.351 | 1.00 | 25.78 | W | O |
| ATOM | 10366 | OW | HOH | W | 311 | 21.388 | 84.869 | 83.059 | 1.00 | 28.13 | W | O |
| ATOM | 10367 | OW | HOH | W | 312 | 7.328 | 79.387 | 88.001 | 1.00 | 24.38 | W | O |
| ATOM | 10368 | OW | HOH | W | 313 | 4.583 | 58.112 | 93.906 | 1.00 | 38.85 | W | O |
| ATOM | 10369 | OW | HOH | W | 314 | 35.963 | 78.765 | 52.587 | 1.00 | 31.56 | W | O |
| ATOM | 10370 | OW | HOH | W | 315 | 33.542 | 78.312 | 82.838 | 1.00 | 30.67 | W | O |
| ATOM | 10371 | OW | HOH | W | 316 | 20.045 | 39.403 | 55.038 | 1.00 | 19.70 | W | O |
| ATOM | 10372 | OW | HOH | W | 317 | 22.707 | 51.411 | 51.504 | 1.00 | 31.21 | W | O |
| ATOM | 10373 | OW | HOH | W | 318 | −3.933 | 47.659 | 32.653 | 1.00 | 13.00 | W | O |
| ATOM | 10374 | OW | HOH | W | 319 | 45.313 | 76.059 | 62.422 | 1.00 | 27.75 | W | O |
| ATOM | 10375 | OW | HOH | W | 320 | 9.163 | 82.802 | 67.646 | 1.00 | 41.84 | W | O |
| ATOM | 10376 | OW | HOH | W | 321 | 17.900 | 71.673 | 72.540 | 1.00 | 17.98 | W | O |
| ATOM | 10377 | OW | HOH | W | 322 | 20.699 | 69.976 | 74.190 | 1.00 | 18.06 | W | O |
| ATOM | 10378 | OW | HOH | W | 323 | 18.630 | 69.242 | 79.859 | 1.00 | 28.26 | W | O |
| ATOM | 10379 | OW | HOH | W | 324 | 26.307 | 64.484 | 50.953 | 1.00 | 24.51 | W | O |
| ATOM | 10380 | OW | HOH | W | 325 | −4.484 | 49.244 | 75.926 | 1.00 | 30.92 | W | O |
| ATOM | 10381 | OW | HOH | W | 326 | −25.147 | 35.324 | 39.087 | 1.00 | 29.13 | W | O |
| ATOM | 10382 | OW | HOH | W | 327 | 15.370 | 87.404 | 82.575 | 1.00 | 17.99 | W | O |
| ATOM | 10383 | OW | HOH | W | 328 | 35.168 | 80.992 | 56.752 | 1.00 | 37.26 | W | O |
| ATOM | 10384 | OW | HOH | W | 329 | −11.276 | 58.797 | 26.264 | 1.00 | 17.54 | W | O |
| ATOM | 10385 | OW | HOH | W | 330 | 7.604 | 87.054 | 76.845 | 1.00 | 24.81 | W | O |
| ATOM | 10386 | OW | HOH | W | 331 | 13.547 | 69.071 | 77.152 | 1.00 | 19.49 | W | O |
| ATOM | 10387 | OW | HOH | W | 332 | 9.854 | 75.538 | 51.266 | 1.00 | 28.88 | W | O |
| ATOM | 10388 | OW | HOH | W | 333 | −36.428 | 33.684 | 68.917 | 1.00 | 38.25 | W | O |
| ATOM | 10389 | OW | HOH | W | 334 | −13.911 | 41.878 | 73.945 | 1.00 | 27.15 | W | O |
| ATOM | 10390 | OW | HOH | W | 335 | −28.172 | 22.125 | 50.919 | 1.00 | 38.70 | W | O |
| ATOM | 10391 | OW | HOH | W | 336 | 22.796 | 70.381 | 78.024 | 1.00 | 19.89 | W | O |
| ATOM | 10392 | OW | HOH | W | 337 | 30.094 | 75.275 | 82.361 | 1.00 | 24.14 | W | O |
| ATOM | 10393 | OW | HOH | W | 338 | −3.239 | 68.063 | 21.951 | 1.00 | 31.43 | W | O |
| ATOM | 10394 | OW | HOH | W | 339 | −13.913 | 41.711 | 40.475 | 1.00 | 22.13 | W | O |
| ATOM | 10395 | OW | HOH | W | 340 | 41.689 | 79.166 | 45.844 | 1.00 | 30.91 | W | O |
| ATOM | 10396 | OW | HOH | W | 341 | 16.357 | 85.367 | 72.475 | 1.00 | 10.42 | W | O |
| ATOM | 10397 | OW | HOH | W | 342 | 28.707 | 84.621 | 47.208 | 1.00 | 25.80 | W | O |
| ATOM | 10398 | OW | HOH | W | 343 | −15.706 | 22.602 | 49.940 | 1.00 | 36.80 | W | O |
| ATOM | 10399 | OW | HOH | W | 344 | −2.868 | 45.490 | 51.646 | 1.00 | 27.21 | W | O |
| ATOM | 10400 | OW | HOH | W | 345 | 3.119 | 24.424 | 31.788 | 1.00 | 33.88 | W | O |
| ATOM | 10401 | OW | HOH | W | 346 | −15.249 | 70.549 | 33.898 | 1.00 | 17.88 | W | O |
| ATOM | 10402 | OW | HOH | W | 347 | −11.408 | 55.832 | 31.956 | 1.00 | 23.74 | W | O |
| ATOM | 10403 | OW | HOH | W | 348 | −28.223 | 37.376 | 30.179 | 1.00 | 31.71 | W | O |
| ATOM | 10404 | OW | HOH | W | 349 | −28.556 | 53.674 | 50.130 | 1.00 | 28.46 | W | O |
| ATOM | 10405 | OW | HOH | W | 350 | 55.829 | 62.564 | 73.714 | 1.00 | 45.26 | W | O |
| ATOM | 10406 | OW | HOH | W | 351 | −2.963 | 29.247 | 31.877 | 1.00 | 42.76 | W | O |
| ATOM | 10407 | OW | HOH | W | 352 | −9.040 | 57.373 | 26.558 | 1.00 | 21.40 | W | O |
| ATOM | 10408 | OW | HOH | W | 353 | −13.481 | 76.087 | 23.868 | 1.00 | 33.94 | W | O |
| ATOM | 10409 | OW | HOH | W | 354 | −10.747 | 55.288 | 26.706 | 1.00 | 26.14 | W | O |
| ATOM | 10410 | OW | HOH | W | 355 | −22.501 | 66.330 | 23.660 | 1.00 | 19.28 | W | O |
| ATOM | 10411 | OW | HOH | W | 356 | −4.462 | 66.087 | 45.073 | 1.00 | 18.29 | W | O |
| ATOM | 10412 | OW | HOH | W | 357 | −30.593 | 57.092 | 27.826 | 1.00 | 32.19 | W | O |
| ATOM | 10413 | OW | HOH | W | 358 | −14.883 | 21.862 | 47.278 | 1.00 | 30.35 | W | O |
| ATOM | 10414 | OW | HOH | W | 359 | 38.571 | 84.479 | 34.642 | 1.00 | 36.25 | W | O |
| ATOM | 10415 | OW | HOH | W | 360 | 39.502 | 80.183 | 69.775 | 1.00 | 34.57 | W | O |
| ATOM | 10416 | OW | HOH | W | 361 | −12.287 | 79.972 | 28.486 | 1.00 | 44.38 | W | O |
| ATOM | 10417 | OW | HOH | W | 362 | 15.007 | 83.174 | 91.639 | 1.00 | 37.45 | W | O |
| ATOM | 10418 | OW | HOH | W | 363 | −26.834 | 31.034 | 57.663 | 1.00 | 20.67 | W | O |
| ATOM | 10419 | OW | HOH | W | 364 | 25.353 | 37.901 | 59.576 | 1.00 | 25.00 | W | O |
| ATOM | 10420 | OW | HOH | W | 365 | 5.581 | 37.731 | 60.947 | 1.00 | 30.06 | W | O |
| ATOM | 10421 | OW | HOH | W | 366 | 11.090 | 56.943 | 43.297 | 1.00 | 35.04 | W | O |
| ATOM | 10422 | OW | HOH | W | 367 | 29.498 | 39.359 | 65.957 | 1.00 | 26.93 | W | O |
| ATOM | 10423 | OW | HOH | W | 368 | 4.122 | 61.933 | 66.590 | 1.00 | 31.11 | W | O |
| ATOM | 10424 | OW | HOH | W | 369 | −15.853 | 41.760 | 75.361 | 1.00 | 34.40 | W | O |
| ATOM | 10425 | OW | HOH | W | 370 | 48.485 | 48.924 | 59.317 | 1.00 | 20.92 | W | O |
| ATOM | 10426 | OW | HOH | W | 371 | 41.100 | 39.576 | 72.372 | 1.00 | 31.79 | W | O |
| ATOM | 10427 | OW | HOH | W | 372 | −3.860 | 48.602 | 52.055 | 1.00 | 16.02 | W | O |
| ATOM | 10428 | OW | HOH | W | 373 | 45.383 | 60.833 | 38.478 | 1.00 | 27.14 | W | O |
| ATOM | 10429 | OW | HOH | W | 374 | 15.611 | 36.732 | 38.347 | 1.00 | 31.34 | W | O |
| ATOM | 10430 | OW | HOH | W | 375 | −12.520 | 78.786 | 25.716 | 1.00 | 34.07 | W | O |
| ATOM | 10431 | OW | HOH | W | 376 | 8.879 | 76.101 | 18.645 | 1.00 | 33.68 | W | O |
| ATOM | 10432 | OW | HOH | W | 377 | 39.218 | 59.419 | 31.034 | 1.00 | 36.20 | W | O |
| ATOM | 10433 | OW | HOH | W | 378 | −27.062 | 55.388 | 32.957 | 1.00 | 24.56 | W | O |
| ATOM | 10434 | OW | HOH | W | 379 | −9.637 | 49.291 | 28.061 | 1.00 | 37.83 | W | O |
| ATOM | 10435 | OW | HOH | W | 380 | 28.401 | 80.550 | 44.954 | 1.00 | 19.82 | W | O |
| ATOM | 10436 | OW | HOH | W | 381 | 4.438 | 45.163 | 67.727 | 1.00 | 30.51 | W | O |
| ATOM | 10437 | OW | HOH | W | 382 | 3.070 | 41.102 | 26.118 | 1.00 | 19.15 | W | O |
| ATOM | 10438 | OW | HOH | W | 383 | 44.397 | 81.747 | 58.762 | 1.00 | 24.47 | W | O |
| ATOM | 10439 | OW | HOH | W | 384 | −2.332 | 59.469 | 71.265 | 1.00 | 34.91 | W | O |
| ATOM | 10440 | OW | HOH | W | 385 | −20.000 | 29.900 | 35.769 | 1.00 | 21.15 | W | O |
| ATOM | 10441 | OW | HOH | W | 386 | 50.813 | 62.024 | 49.744 | 1.00 | 26.97 | W | O |
| ATOM | 10442 | OW | HOH | W | 387 | 39.856 | 59.641 | 50.517 | 1.00 | 20.91 | W | O |
| ATOM | 10443 | OW | HOH | W | 388 | 37.472 | 62.715 | 48.133 | 1.00 | 26.57 | W | O |
| ATOM | 10444 | OW | HOH | W | 389 | 36.633 | 60.073 | 31.329 | 1.00 | 35.50 | W | O |
| ATOM | 10445 | OW | HOH | W | 390 | −28.458 | 45.973 | 38.611 | 1.00 | 34.45 | W | O |
| ATOM | 10446 | OW | HOH | W | 391 | 30.110 | 83.983 | 64.160 | 1.00 | 25.41 | W | O |
| ATOM | 10447 | OW | HOH | W | 392 | 25.925 | 78.898 | 72.015 | 1.00 | 14.45 | W | O |
| ATOM | 10448 | OW | HOH | W | 393 | 0.972 | 43.645 | 55.046 | 1.00 | 32.18 | W | O |
| ATOM | 10449 | OW | HOH | W | 394 | 42.445 | 82.113 | 40.751 | 1.00 | 31.02 | W | O |
| ATOM | 10450 | OW | HOH | W | 395 | 48.445 | 72.365 | 45.331 | 1.00 | 26.35 | W | O |
| ATOM | 10451 | OW | HOH | W | 396 | 32.783 | 79.050 | 30.592 | 1.00 | 31.32 | W | O |
| ATOM | 10452 | OW | HOH | W | 397 | 23.471 | 87.653 | 68.904 | 1.00 | 23.75 | W | O |
| ATOM | 10453 | OW | HOH | W | 398 | 19.738 | 71.674 | 77.731 | 1.00 | 22.05 | W | O |
| ATOM | 10454 | OW | HOH | W | 399 | 31.901 | 38.883 | 67.720 | 1.00 | 34.99 | W | O |
| ATOM | 10455 | OW | HOH | W | 400 | 40.277 | 65.722 | 74.913 | 1.00 | 22.62 | W | O |
| ATOM | 10456 | OW | HOH | W | 401 | −14.556 | 77.285 | 29.455 | 1.00 | 31.98 | W | O |
| ATOM | 10457 | OW | HOH | W | 402 | 37.829 | 61.757 | 50.868 | 1.00 | 24.74 | W | O |
| ATOM | 10458 | OW | HOH | W | 403 | −30.175 | 54.029 | 65.283 | 1.00 | 33.27 | W | O |
| ATOM | 10459 | OW | HOH | W | 404 | 35.638 | 63.463 | 45.117 | 1.00 | 25.62 | W | O |
| ATOM | 10460 | OW | HOH | W | 405 | 25.566 | 50.067 | 46.787 | 1.00 | 27.80 | W | O |
| ATOM | 10461 | OW | HOH | W | 406 | 48.117 | 58.968 | 45.708 | 1.00 | 28.35 | W | O |
| ATOM | 10462 | OW | HOH | W | 407 | 42.657 | 63.014 | 36.526 | 1.00 | 27.93 | W | O |
| ATOM | 10463 | OW | HOH | W | 408 | 38.198 | 84.684 | 75.233 | 1.00 | 33.14 | W | O |
| ATOM | 10464 | OW | HOH | W | 409 | −16.692 | 35.529 | 56.123 | 1.00 | 17.97 | W | O |
| ATOM | 10465 | OW | HOH | W | 410 | −14.571 | 54.985 | 25.986 | 1.00 | 19.35 | W | O |
| ATOM | 10466 | OW | HOH | W | 411 | 19.591 | 73.405 | 75.622 | 1.00 | 30.03 | W | O |
| ATOM | 10467 | OW | HOH | W | 412 | −7.377 | 39.449 | 28.931 | 1.00 | 27.41 | W | O |
| ATOM | 10468 | OW | HOH | W | 413 | 7.213 | 85.283 | 81.777 | 1.00 | 31.54 | W | O |
| ATOM | 10469 | OW | HOH | W | 414 | −21.425 | 51.470 | 49.399 | 1.00 | 19.42 | W | O |
| ATOM | 10470 | OW | HOH | W | 415 | −12.850 | 56.726 | 20.112 | 1.00 | 26.44 | W | O |
| ATOM | 10471 | OW | HOH | W | 416 | −18.518 | 37.329 | 37.397 | 1.00 | 20.84 | W | O |
| ATOM | 10472 | OW | HOH | W | 417 | 18.283 | 68.775 | 77.243 | 1.00 | 26.24 | W | O |
| ATOM | 10473 | OW | HOH | W | 418 | 35.892 | 60.196 | 69.872 | 1.00 | 37.85 | W | O |
| ATOM | 10474 | OW | HOH | W | 419 | −19.988 | 18.760 | 31.587 | 1.00 | 41.12 | W | O |
| ATOM | 10475 | OW | HOH | W | 420 | −16.743 | 30.509 | 56.148 | 1.00 | 19.90 | W | O |
| ATOM | 10476 | OW | HOH | W | 421 | 17.466 | 43.592 | 76.685 | 1.00 | 25.30 | W | O |
| ATOM | 10477 | OW | HOH | W | 422 | 31.533 | 74.248 | 57.216 | 1.00 | 22.01 | W | O |
| ATOM | 10478 | OW | HOH | W | 423 | 21.441 | 71.439 | 86.560 | 1.00 | 29.82 | W | O |
| ATOM | 10479 | OW | HOH | W | 424 | −7.102 | 23.755 | 31.908 | 1.00 | 40.82 | W | O |
| ATOM | 10480 | OW | HOH | W | 425 | −25.511 | 53.362 | 23.724 | 1.00 | 30.94 | W | O |
| ATOM | 10481 | OW | HOH | W | 426 | −19.685 | 27.407 | 39.496 | 1.00 | 14.70 | W | O |
| ATOM | 10482 | OW | HOH | W | 427 | −26.181 | 68.778 | 22.843 | 1.00 | 32.25 | W | O |
| ATOM | 10483 | OW | HOH | W | 428 | 15.789 | 40.290 | 34.960 | 1.00 | 27.94 | W | O |
| ATOM | 10484 | OW | HOH | W | 429 | 2.296 | 23.424 | 48.253 | 1.00 | 25.14 | W | O |
| ATOM | 10485 | OW | HOH | W | 430 | 47.029 | 59.295 | 48.417 | 1.00 | 26.25 | W | O |
| ATOM | 10486 | OW | HOH | W | 431 | 18.503 | 58.897 | 44.658 | 1.00 | 44.13 | W | O |
| ATOM | 10487 | OW | HOH | W | 432 | −21.784 | 27.148 | 33.529 | 1.00 | 35.31 | W | O |
| ATOM | 10488 | OW | HOH | W | 433 | 21.830 | 52.531 | 90.645 | 1.00 | 61.47 | W | O |
| ATOM | 10489 | OW | HOH | W | 434 | 41.635 | 70.541 | 65.500 | 1.00 | 20.36 | W | O |
| ATOM | 10490 | OW | HOH | W | 435 | 7.131 | 74.944 | 82.237 | 1.00 | 21.71 | W | O |
| ATOM | 10491 | P | PO4 | X | 897 | 17.459 | 47.697 | 57.351 | 1.00 | 47.58 | X | P |
| ATOM | 10492 | O1 | PO4 | X | 897 | 17.225 | 48.234 | 58.732 | 1.00 | 45.95 | X | O |
| ATOM | 10493 | O2 | PO4 | X | 897 | 18.363 | 48.632 | 56.633 | 1.00 | 51.25 | X | O |
| ATOM | 10494 | O3 | PO4 | X | 897 | 16.153 | 47.537 | 56.607 | 1.00 | 46.86 | X | O |
| ATOM | 10495 | O4 | PO4 | X | 897 | 18.227 | 46.420 | 57.368 | 1.00 | 48.65 | X | O |
| ATOM | 10496 | P | PO4 | X | 898 | 7.050 | 42.922 | 49.152 | 1.00 | 52.48 | X | P |
| ATOM | 10497 | O1 | PO4 | X | 898 | 7.310 | 43.433 | 50.552 | 1.00 | 55.01 | X | O |
| ATOM | 10498 | O2 | PO4 | X | 898 | 7.824 | 43.704 | 48.150 | 1.00 | 49.85 | X | O |
| ATOM | 10499 | O3 | PO4 | X | 898 | 5.633 | 43.055 | 48.733 | 1.00 | 54.04 | X | O |
| ATOM | 10500 | O4 | PO4 | X | 898 | 7.389 | 41.472 | 49.100 | 1.00 | 53.68 | X | O |

TABLE 3
Atomic coordinates for AMPDA with coformycin

| REMARK | xplor input | | | |
|---|---|---|---|---|
| CRYST1 | 148.693 148.693 158.499 90.00 90.00 90.00 P42212 | | | |
| SCALE1 | 0.00673 | 0.00000 | 0.00000 | 0.00000 |
| SCALE2 | 0.00000 | 0.00673 | 0.00000 | 0.00000 |
| SCALE3 | 0.00000 | 0.00000 | 0.00631 | 0.00000 |

| REMARK | FILENAME = “brefinement.pdb” | | | | | | | | | | | |
|---|---|---|---|---|---|---|---|---|---|---|---|---|
| REMARK | r = 0.236254 free_r = 0.272333 | | | | | | | | | | | |
| REMARK | DATE: 28-Mar-00 16:07:25 created by user: chrisp | | | | | | | | | | | |
| ATOM | 1 | CB | SER | A | 106 | 17.469 | 72.894 | 93.220 | 1.00 | 42.33 | A | C |
| ATOM | 2 | OG | SER | A | 106 | 18.455 | 73.447 | 92.358 | 1.00 | 44.48 | A | O |
| ATOM | 3 | C | SER | A | 106 | 18.654 | 74.571 | 94.656 | 1.00 | 41.87 | A | C |
| ATOM | 4 | O | SER | A | 106 | 18.497 | 75.734 | 94.274 | 1.00 | 43.15 | A | O |
| ATOM | 5 | N | SER | A | 106 | 16.194 | 74.229 | 94.880 | 1.00 | 40.00 | A | N |
| ATOM | 6 | CA | SER | A | 106 | 17.501 | 73.561 | 94.599 | 1.00 | 41.47 | A | C |
| ATOM | 7 | N | PRO | A | 107 | 19.834 | 74.130 | 95.127 | 1.00 | 39.96 | A | N |
| ATOM | 8 | CD | PRO | A | 107 | 20.140 | 72.766 | 95.587 | 1.00 | 37.58 | A | C |
| ATOM | 9 | CA | PRO | A | 107 | 21.001 | 75.014 | 95.228 | 1.00 | 38.80 | A | C |
| ATOM | 10 | CB | PRO | A | 107 | 22.043 | 74.167 | 95.970 | 1.00 | 35.25 | A | C |
| ATOM | 11 | CG | PRO | A | 107 | 21.314 | 72.971 | 96.481 | 1.00 | 34.22 | A | C |
| ATOM | 12 | C | PRO | A | 107 | 21.552 | 75.543 | 93.896 | 1.00 | 39.86 | A | C |
| ATOM | 13 | O | PRO | A | 107 | 22.197 | 76.595 | 93.866 | 1.00 | 41.80 | A | O |
| ATOM | 14 | N | THR | A | 108 | 21.292 | 74.833 | 92.800 | 1.00 | 39.07 | A | N |
| ATOM | 15 | CA | THR | A | 108 | 21.812 | 75.241 | 91.495 | 1.00 | 38.25 | A | C |
| ATOM | 16 | CB | THR | A | 108 | 22.009 | 74.014 | 90.567 | 1.00 | 38.74 | A | C |
| ATOM | 17 | OG1 | THR | A | 108 | 20.768 | 73.690 | 89.923 | 1.00 | 39.26 | A | O |
| ATOM | 18 | CG2 | THR | A | 108 | 22.497 | 72.807 | 91.371 | 1.00 | 37.76 | A | C |
| ATOM | 19 | C | THR | A | 108 | 21.010 | 76.296 | 90.727 | 1.00 | 38.48 | A | C |
| ATOM | 20 | O | THR | A | 108 | 21.333 | 76.600 | 89.577 | 1.00 | 38.30 | A | O |
| ATOM | 21 | N | TYR | A | 109 | 19.981 | 76.866 | 91.349 | 1.00 | 37.86 | A | N |
| ATOM | 22 | CA | TYR | A | 109 | 19.172 | 77.884 | 90.675 | 1.00 | 34.64 | A | C |
| ATOM | 23 | CB | TYR | A | 109 | 17.685 | 77.616 | 90.918 | 1.00 | 34.09 | A | C |
| ATOM | 24 | CG | TYR | A | 109 | 17.085 | 76.671 | 89.902 | 1.00 | 37.11 | A | C |
| ATOM | 25 | CD1 | TYR | A | 109 | 17.812 | 75.574 | 89.426 | 1.00 | 37.43 | A | C |
| ATOM | 26 | CE1 | TYR | A | 109 | 17.272 | 74.703 | 88.482 | 1.00 | 36.06 | A | C |
| ATOM | 27 | CD2 | TYR | A | 109 | 15.800 | 76.872 | 89.406 | 1.00 | 35.75 | A | C |
| ATOM | 28 | CE2 | TYR | A | 109 | 15.251 | 76.007 | 88.462 | 1.00 | 37.53 | A | C |
| ATOM | 29 | CZ | TYR | A | 109 | 15.991 | 74.925 | 88.004 | 1.00 | 37.19 | A | C |
| ATOM | 30 | OH | TYR | A | 109 | 15.442 | 74.064 | 87.075 | 1.00 | 35.16 | A | O |
| ATOM | 31 | C | TYR | A | 109 | 19.527 | 79.296 | 91.124 | 1.00 | 31.80 | A | C |
| ATOM | 32 | O | TYR | A | 109 | 18.813 | 80.251 | 90.832 | 1.00 | 31.02 | A | O |
| ATOM | 33 | N | GLN | A | 110 | 20.645 | 79.419 | 91.829 | 1.00 | 31.25 | A | N |
| ATOM | 34 | CA | GLN | A | 110 | 21.099 | 80.709 | 92.330 | 1.00 | 31.63 | A | C |
| ATOM | 35 | CB | GLN | A | 110 | 22.424 | 80.539 | 93.080 | 1.00 | 31.57 | A | C |
| ATOM | 36 | CG | GLN | A | 110 | 22.849 | 81.761 | 93.887 | 1.00 | 32.77 | A | C |
| ATOM | 37 | CD | GLN | A | 110 | 21.901 | 82.052 | 95.038 | 1.00 | 33.60 | A | C |
| ATOM | 38 | OE1 | GLN | A | 110 | 21.056 | 81.222 | 95.386 | 1.00 | 34.22 | A | O |
| ATOM | 39 | NE2 | GLN | A | 110 | 22.035 | 83.236 | 95.635 | 1.00 | 31.89 | A | N |
| ATOM | 40 | C | GLN | A | 110 | 21.306 | 81.688 | 91.190 | 1.00 | 31.23 | A | C |
| ATOM | 41 | O | GLN | A | 110 | 21.295 | 82.909 | 91.379 | 1.00 | 31.20 | A | O |
| ATOM | 42 | N | THR | A | 111 | 21.482 | 81.137 | 89.997 | 1.00 | 29.81 | A | N |
| ATOM | 43 | CA | THR | A | 111 | 21.757 | 81.941 | 88.823 | 1.00 | 27.75 | A | C |
| ATOM | 44 | CB | THR | A | 111 | 23.001 | 81.365 | 88.124 | 1.00 | 25.09 | A | C |
| ATOM | 45 | OG1 | THR | A | 111 | 23.705 | 82.418 | 87.467 | 1.00 | 32.06 | A | O |
| ATOM | 46 | CG2 | THR | A | 111 | 22.612 | 80.290 | 87.131 | 1.00 | 23.52 | A | C |
| ATOM | 47 | C | THR | A | 111 | 20.589 | 82.053 | 87.835 | 1.00 | 25.83 | A | C |
| ATOM | 48 | O | THR | A | 111 | 20.670 | 82.797 | 86.853 | 1.00 | 25.00 | A | O |
| ATOM | 49 | N | VAL | A | 112 | 19.508 | 81.326 | 88.116 | 1.00 | 21.78 | A | N |
| ATOM | 50 | CA | VAL | A | 112 | 18.314 | 81.299 | 87.271 | 1.00 | 18.40 | A | C |
| ATOM | 51 | CB | VAL | A | 112 | 17.647 | 79.898 | 87.305 | 1.00 | 14.26 | A | C |
| ATOM | 52 | CG1 | VAL | A | 112 | 16.462 | 79.862 | 86.365 | 1.00 | 6.66 | A | C |
| ATOM | 53 | CG2 | VAL | A | 112 | 18.661 | 78.827 | 86.949 | 1.00 | 11.08 | A | C |
| ATOM | 54 | C | VAL | A | 112 | 17.244 | 82.313 | 87.682 | 1.00 | 19.45 | A | C |
| ATOM | 55 | O | VAL | A | 112 | 16.745 | 82.271 | 88.803 | 1.00 | 23.56 | A | O |
| ATOM | 56 | N | PRO | A | 113 | 16.869 | 83.228 | 86.774 | 1.00 | 17.94 | A | N |
| ATOM | 57 | CD | PRO | A | 113 | 17.393 | 83.420 | 85.416 | 1.00 | 14.36 | A | C |
| ATOM | 58 | CA | PRO | A | 113 | 15.842 | 84.225 | 87.094 | 1.00 | 17.47 | A | C |
| ATOM | 59 | CB | PRO | A | 113 | 15.927 | 85.225 | 85.939 | 1.00 | 15.37 | A | C |
| ATOM | 60 | CG | PRO | A | 113 | 17.195 | 84.884 | 85.206 | 1.00 | 12.74 | A | C |
| ATOM | 61 | C | PRO | A | 113 | 14.450 | 83.601 | 87.183 | 1.00 | 21.21 | A | C |
| ATOM | 62 | O | PRO | A | 113 | 14.233 | 82.454 | 86.786 | 1.00 | 21.71 | A | O |
| ATOM | 63 | N | ASP | A | 114 | 13.505 | 84.362 | 87.715 | 1.00 | 24.01 | A | N |
| ATOM | 64 | CA | ASP | A | 114 | 12.137 | 83.889 | 87.831 | 1.00 | 25.11 | A | C |
| ATOM | 65 | CB | ASP | A | 114 | 11.327 | 84.807 | 88.754 | 1.00 | 27.71 | A | C |
| ATOM | 66 | CG | ASP | A | 114 | 11.695 | 84.647 | 90.217 | 1.00 | 33.29 | A | C |
| ATOM | 67 | OD1 | ASP | A | 114 | 12.155 | 83.550 | 90.603 | 1.00 | 37.45 | A | O |
| ATOM | 68 | OD2 | ASP | A | 114 | 11.523 | 85.623 | 90.982 | 1.00 | 33.72 | A | O |
| ATOM | 69 | C | ASP | A | 114 | 11.512 | 83.932 | 86.445 | 1.00 | 23.59 | A | C |
| ATOM | 70 | O | ASP | A | 114 | 11.899 | 84.748 | 85.608 | 1.00 | 23.68 | A | O |
| ATOM | 71 | N | PHE | A | 115 | 10.559 | 83.043 | 86.202 | 1.00 | 18.87 | A | N |
| ATOM | 72 | CA | PHE | A | 115 | 9.837 | 83.020 | 84.940 | 1.00 | 18.21 | A | C |
| ATOM | 73 | CB | PHE | A | 115 | 10.720 | 82.495 | 83.793 | 1.00 | 14.68 | A | C |
| ATOM | 74 | CG | PHE | A | 115 | 11.083 | 81.040 | 83.897 | 1.00 | 10.29 | A | C |
| ATOM | 75 | CD1 | PHE | A | 115 | 12.180 | 80.634 | 84.643 | 1.00 | 10.25 | A | C |
| ATOM | 76 | CD2 | PHE | A | 115 | 10.355 | 80.082 | 83.207 | 1.00 | 10.02 | A | C |
| ATOM | 77 | CE1 | PHE | A | 115 | 12.548 | 79.297 | 84.699 | 1.00 | 9.90 | A | C |
| ATOM | 78 | CE2 | PHE | A | 115 | 10.714 | 78.739 | 83.257 | 1.00 | 12.56 | A | C |
| ATOM | 79 | CZ | PHE | A | 115 | 11.814 | 78.345 | 84.004 | 1.00 | 9.41 | A | C |
| ATOM | 80 | C | PHE | A | 115 | 8.595 | 82.163 | 85.151 | 1.00 | 18.52 | A | C |
| ATOM | 81 | O | PHE | A | 115 | 8.564 | 81.328 | 86.059 | 1.00 | 16.51 | A | O |
| ATOM | 82 | N | GLN | A | 116 | 7.564 | 82.386 | 84.340 | 1.00 | 18.52 | A | N |
| ATOM | 83 | CA | GLN | A | 116 | 6.319 | 81.644 | 84.485 | 1.00 | 17.37 | A | C |
| ATOM | 84 | CB | GLN | A | 116 | 5.181 | 82.415 | 83.823 | 1.00 | 17.42 | A | C |
| ATOM | 85 | CG | GLN | A | 116 | 4.935 | 83.771 | 84.466 | 1.00 | 19.34 | A | C |
| ATOM | 86 | CD | GLN | A | 116 | 3.799 | 84.529 | 83.820 | 1.00 | 21.38 | A | C |
| ATOM | 87 | OE1 | GLN | A | 116 | 3.986 | 85.188 | 82.796 | 1.00 | 23.27 | A | O |
| ATOM | 88 | NE2 | GLN | A | 116 | 2.610 | 84.446 | 84.418 | 1.00 | 20.69 | A | N |
| ATOM | 89 | C | GLN | A | 116 | 6.402 | 80.234 | 83.932 | 1.00 | 16.28 | A | C |
| ATOM | 90 | O | GLN | A | 116 | 6.935 | 80.004 | 82.848 | 1.00 | 19.12 | A | O |
| ATOM | 91 | N | ARG | A | 117 | 5.873 | 79.287 | 84.694 | 1.00 | 16.67 | A | N |
| ATOM | 92 | CA | ARG | A | 117 | 5.893 | 77.891 | 84.299 | 1.00 | 15.52 | A | C |
| ATOM | 93 | CB | ARG | A | 117 | 6.566 | 77.053 | 85.382 | 1.00 | 13.87 | A | C |
| ATOM | 94 | CG | ARG | A | 117 | 8.081 | 77.150 | 85.375 | 1.00 | 17.86 | A | C |
| ATOM | 95 | CD | ARG | A | 117 | 8.652 | 76.685 | 86.695 | 1.00 | 19.56 | A | C |
| ATOM | 96 | NE | ARG | A | 117 | 10.112 | 76.726 | 86.730 | 1.00 | 20.65 | A | N |
| ATOM | 97 | CZ | ARG | A | 117 | 10.818 | 77.741 | 87.217 | 1.00 | 19.57 | A | C |
| ATOM | 98 | NH1 | ARG | A | 117 | 10.200 | 78.801 | 87.706 | 1.00 | 18.46 | A | N |
| ATOM | 99 | NH2 | ARG | A | 117 | 12.142 | 77.685 | 87.241 | 1.00 | 22.16 | A | N |
| ATOM | 100 | C | ARG | A | 117 | 4.500 | 77.347 | 84.053 | 1.00 | 16.68 | A | C |
| ATOM | 101 | O | ARG | A | 117 | 3.504 | 77.926 | 84.491 | 1.00 | 16.14 | A | O |
| ATOM | 102 | N | VAL | A | 118 | 4.436 | 76.225 | 83.345 | 1.00 | 16.52 | A | N |
| ATOM | 103 | CA | VAL | A | 118 | 3.163 | 75.595 | 83.067 | 1.00 | 19.49 | A | C |
| ATOM | 104 | CB | VAL | A | 118 | 2.906 | 75.438 | 81.536 | 1.00 | 19.15 | A | C |
| ATOM | 105 | CG1 | VAL | A | 118 | 4.134 | 75.837 | 80.754 | 1.00 | 19.29 | A | C |
| ATOM | 106 | CG2 | VAL | A | 118 | 2.469 | 74.019 | 81.203 | 1.00 | 17.28 | A | C |
| ATOM | 107 | C | VAL | A | 118 | 3.165 | 74.243 | 83.746 | 1.00 | 20.55 | A | C |
| ATOM | 108 | O | VAL | A | 118 | 4.035 | 73.412 | 83.498 | 1.00 | 23.13 | A | O |
| ATOM | 109 | N | GLN | A | 119 | 2.199 | 74.035 | 84.630 | 1.00 | 22.01 | A | N |
| ATOM | 110 | CA | GLN | A | 119 | 2.113 | 72.774 | 85.333 | 1.00 | 23.44 | A | C |
| ATOM | 111 | CB | GLN | A | 119 | 2.481 | 72.952 | 86.806 | 1.00 | 24.94 | A | C |
| ATOM | 112 | CG | GLN | A | 119 | 1.832 | 74.137 | 87.485 | 1.00 | 35.23 | A | C |
| ATOM | 113 | CD | GLN | A | 119 | 2.132 | 74.181 | 88.983 | 1.00 | 39.74 | A | C |
| ATOM | 114 | OE1 | GLN | A | 119 | 1.265 | 73.887 | 89.815 | 1.00 | 39.12 | A | O |
| ATOM | 115 | NE2 | GLN | A | 119 | 3.365 | 74.547 | 89.329 | 1.00 | 35.75 | A | N |
| ATOM | 116 | C | GLN | A | 119 | 0.722 | 72.189 | 85.193 | 1.00 | 21.38 | A | C |
| ATOM | 117 | O | GLN | A | 119 | −0.263 | 72.915 | 85.093 | 1.00 | 20.79 | A | O |
| ATOM | 118 | N | ILE | A | 120 | 0.665 | 70.864 | 85.169 | 1.00 | 19.99 | A | N |
| ATOM | 119 | CA | ILE | A | 120 | −0.578 | 70.143 | 85.020 | 1.00 | 17.52 | A | C |
| ATOM | 120 | CB | ILE | A | 120 | −0.422 | 68.999 | 84.000 | 1.00 | 15.52 | A | C |
| ATOM | 121 | CG2 | ILE | A | 120 | −1.770 | 68.360 | 83.721 | 1.00 | 13.36 | A | C |
| ATOM | 122 | CG1 | ILE | A | 120 | 0.222 | 69.533 | 82.720 | 1.00 | 11.94 | A | C |
| ATOM | 123 | CD1 | ILE | A | 120 | −0.481 | 70.737 | 82.129 | 1.00 | 9.16 | A | C |
| ATOM | 124 | C | ILE | A | 120 | −0.994 | 69.555 | 86.351 | 1.00 | 20.82 | A | C |
| ATOM | 125 | O | ILE | A | 120 | −0.209 | 68.879 | 87.014 | 1.00 | 21.02 | A | O |
| ATOM | 126 | N | THR | A | 121 | −2.234 | 69.822 | 86.739 | 1.00 | 24.35 | A | N |
| ATOM | 127 | CA | THR | A | 121 | −2.776 | 69.307 | 87.986 | 1.00 | 27.02 | A | C |
| ATOM | 128 | CB | THR | A | 121 | −3.664 | 70.354 | 88.682 | 1.00 | 25.39 | A | C |
| ATOM | 129 | OG1 | THR | A | 121 | −4.889 | 70.491 | 87.960 | 1.00 | 26.55 | A | O |
| ATOM | 130 | CG2 | THR | A | 121 | −2.960 | 71.701 | 88.740 | 1.00 | 23.44 | A | C |
| ATOM | 131 | C | THR | A | 121 | −3.615 | 68.074 | 87.683 | 1.00 | 29.65 | A | C |
| ATOM | 132 | O | THR | A | 121 | −4.097 | 67.906 | 86.565 | 1.00 | 32.98 | A | O |
| ATOM | 133 | N | GLY | A | 122 | −3.782 | 67.207 | 88.676 | 1.00 | 31.96 | A | N |
| ATOM | 134 | CA | GLY | A | 122 | −4.575 | 66.009 | 88.478 | 1.00 | 34.06 | A | C |
| ATOM | 135 | C | GLY | A | 122 | −3.753 | 64.755 | 88.264 | 1.00 | 37.53 | A | C |
| ATOM | 136 | O | GLY | A | 122 | −2.541 | 64.816 | 88.061 | 1.00 | 37.19 | A | O |
| ATOM | 137 | N | ASP | A | 123 | −4.426 | 63.609 | 88.310 | 1.00 | 41.38 | A | N |
| ATOM | 138 | CA | ASP | A | 123 | −3.777 | 62.316 | 88.123 | 1.00 | 45.34 | A | C |
| ATOM | 139 | CB | ASP | A | 123 | −4.588 | 61.210 | 88.801 | 1.00 | 49.75 | A | C |
| ATOM | 140 | CG | ASP | A | 123 | −4.654 | 61.377 | 90.302 | 1.00 | 54.65 | A | C |
| ATOM | 141 | OD1 | ASP | A | 123 | −3.583 | 61.564 | 90.923 | 1.00 | 54.71 | A | O |
| ATOM | 142 | OD2 | ASP | A | 123 | −5.776 | 61.321 | 90.855 | 1.00 | 59.67 | A | O |
| ATOM | 143 | C | ASP | A | 123 | −3.647 | 61.993 | 86.650 | 1.00 | 45.18 | A | C |
| ATOM | 144 | O | ASP | A | 123 | −4.614 | 62.114 | 85.896 | 1.00 | 46.10 | A | O |
| ATOM | 145 | N | TYR | A | 124 | −2.455 | 61.574 | 86.243 | 1.00 | 43.78 | A | N |
| ATOM | 146 | CA | TYR | A | 124 | −2.220 | 61.232 | 84.850 | 1.00 | 43.30 | A | C |
| ATOM | 147 | CB | TYR | A | 124 | −0.716 | 61.160 | 84.574 | 1.00 | 40.50 | A | C |
| ATOM | 148 | CG | TYR | A | 124 | −0.126 | 62.484 | 84.148 | 1.00 | 36.03 | A | C |
| ATOM | 149 | CD1 | TYR | A | 124 | 0.366 | 63.387 | 85.091 | 1.00 | 34.01 | A | C |
| ATOM | 150 | CE1 | TYR | A | 124 | 0.884 | 64.622 | 84.705 | 1.00 | 30.75 | A | C |
| ATOM | 151 | CD2 | TYR | A | 124 | −0.081 | 62.847 | 82.805 | 1.00 | 32.07 | A | C |
| ATOM | 152 | CE2 | TYR | A | 124 | 0.436 | 64.077 | 82.411 | 1.00 | 30.66 | A | C |
| ATOM | 153 | CZ | TYR | A | 124 | 0.915 | 64.959 | 83.365 | 1.00 | 29.12 | A | C |
| ATOM | 154 | OH | TYR | A | 124 | 1.411 | 66.179 | 82.973 | 1.00 | 27.16 | A | O |
| ATOM | 155 | C | TYR | A | 124 | −2.887 | 59.902 | 84.514 | 1.00 | 44.21 | A | C |
| ATOM | 156 | O | TYR | A | 124 | −2.652 | 58.923 | 85.254 | 1.00 | 46.34 | A | O |
| ATOM | 157 | OT | TYR | A | 124 | −3.646 | 59.861 | 83.521 | 1.00 | 42.41 | A | O |
| ATOM | 158 | CB | ASP | B | 132 | −2.811 | 49.126 | 79.403 | 1.00 | 53.85 | B | C |
| ATOM | 159 | CG | ASP | B | 132 | −2.792 | 49.618 | 77.960 | 1.00 | 57.50 | B | C |
| ATOM | 160 | OD1 | ASP | B | 132 | −2.618 | 50.841 | 77.752 | 1.00 | 56.26 | B | O |
| ATOM | 161 | OD2 | ASP | B | 132 | −2.955 | 48.782 | 77.039 | 1.00 | 59.13 | B | O |
| ATOM | 162 | C | ASP | B | 132 | −0.397 | 49.659 | 79.771 | 1.00 | 49.79 | B | C |
| ATOM | 163 | O | ASP | B | 132 | 0.517 | 49.597 | 78.944 | 1.00 | 49.70 | B | O |
| ATOM | 164 | N | ASP | B | 132 | −1.550 | 48.056 | 81.259 | 1.00 | 49.05 | B | N |
| ATOM | 165 | CA | ASP | B | 132 | −1.457 | 48.567 | 79.856 | 1.00 | 50.93 | B | C |
| ATOM | 166 | N | PHE | B | 133 | −0.534 | 50.664 | 80.629 | 1.00 | 48.13 | B | N |
| ATOM | 167 | CA | PHE | B | 133 | 0.418 | 51.765 | 80.681 | 1.00 | 44.41 | B | C |
| ATOM | 168 | CB | PHE | B | 133 | −0.124 | 52.885 | 81.575 | 1.00 | 42.25 | B | C |
| ATOM | 169 | CG | PHE | B | 133 | 0.828 | 54.035 | 81.755 | 1.00 | 42.49 | B | C |
| ATOM | 170 | CD1 | PHE | B | 133 | 1.084 | 54.548 | 83.025 | 1.00 | 38.96 | B | C |
| ATOM | 171 | CD2 | PHE | B | 133 | 1.477 | 54.603 | 80.652 | 1.00 | 42.67 | B | C |
| ATOM | 172 | CE1 | PHE | B | 133 | 1.972 | 55.610 | 83.200 | 1.00 | 39.72 | B | C |
| ATOM | 173 | CE2 | PHE | B | 133 | 2.368 | 55.666 | 80.812 | 1.00 | 41.60 | B | C |
| ATOM | 174 | CZ | PHE | B | 133 | 2.618 | 56.172 | 82.093 | 1.00 | 41.66 | B | C |
| ATOM | 175 | C | PHE | B | 133 | 1.701 | 51.199 | 81.275 | 1.00 | 43.31 | B | C |
| ATOM | 176 | O | PHE | B | 133 | 2.800 | 51.684 | 81.010 | 1.00 | 44.16 | B | O |
| ATOM | 177 | N | GLU | B | 134 | 1.542 | 50.158 | 82.083 | 1.00 | 43.36 | B | N |
| ATOM | 178 | CA | GLU | B | 134 | 2.667 | 49.502 | 82.728 | 1.00 | 41.99 | B | C |
| ATOM | 179 | CB | GLU | B | 134 | 2.161 | 48.370 | 83.625 | 1.00 | 45.83 | B | C |
| ATOM | 180 | CG | GLU | B | 134 | 2.672 | 48.438 | 85.059 | 1.00 | 52.01 | B | C |
| ATOM | 181 | CD | GLU | B | 134 | 3.404 | 47.176 | 85.476 | 1.00 | 55.26 | B | C |
| ATOM | 182 | OE1 | GLU | B | 134 | 2.873 | 46.072 | 85.227 | 1.00 | 56.85 | B | O |
| ATOM | 183 | OE2 | GLU | B | 134 | 4.509 | 47.291 | 86.050 | 1.00 | 56.25 | B | O |
| ATOM | 184 | C | GLU | B | 134 | 3.618 | 48.937 | 81.685 | 1.00 | 39.68 | B | C |
| ATOM | 185 | O | GLU | B | 134 | 4.837 | 49.097 | 81.782 | 1.00 | 38.43 | B | O |
| ATOM | 186 | N | ILE | B | 135 | 3.054 | 48.270 | 80.685 | 1.00 | 37.94 | B | N |
| ATOM | 187 | CA | ILE | B | 135 | 3.865 | 47.674 | 79.637 | 1.00 | 36.57 | B | C |
| ATOM | 188 | CB | ILE | B | 135 | 3.022 | 46.717 | 78.741 | 1.00 | 39.47 | B | C |
| ATOM | 189 | CG2 | ILE | B | 135 | 1.986 | 45.977 | 79.591 | 1.00 | 38.38 | B | C |
| ATOM | 190 | CG1 | ILE | B | 135 | 2.336 | 47.501 | 77.622 | 1.00 | 43.38 | B | C |
| ATOM | 191 | CD1 | ILE | B | 135 | 2.969 | 47.277 | 76.251 | 1.00 | 46.17 | B | C |
| ATOM | 192 | C | ILE | B | 135 | 4.518 | 48.746 | 78.780 | 1.00 | 33.21 | B | C |
| ATOM | 193 | O | ILE | B | 135 | 5.596 | 48.537 | 78.231 | 1.00 | 34.86 | B | O |
| ATOM | 194 | N | VAL | B | 136 | 3.865 | 49.896 | 78.663 | 1.00 | 29.53 | B | N |
| ATOM | 195 | CA | VAL | B | 136 | 4.419 | 50.979 | 77.870 | 1.00 | 26.84 | B | C |
| ATOM | 196 | CB | VAL | B | 136 | 3.398 | 52.133 | 77.682 | 1.00 | 26.29 | B | C |
| ATOM | 197 | CG1 | VAL | B | 136 | 4.088 | 53.341 | 77.070 | 1.00 | 23.48 | B | C |
| ATOM | 198 | CG2 | VAL | B | 136 | 2.246 | 51.678 | 76.800 | 1.00 | 22.26 | B | C |
| ATOM | 199 | C | VAL | B | 136 | 5.638 | 51.505 | 78.611 | 1.00 | 26.14 | B | C |
| ATOM | 200 | O | VAL | B | 136 | 6.708 | 51.677 | 78.030 | 1.00 | 28.18 | B | O |
| ATOM | 201 | N | CYS | B | 137 | 5.473 | 51.748 | 79.906 | 1.00 | 23.95 | B | N |
| ATOM | 202 | CA | CYS | B | 137 | 6.557 | 52.256 | 80.733 | 1.00 | 22.30 | B | C |
| ATOM | 203 | CB | CYS | B | 137 | 6.047 | 52.556 | 82.142 | 1.00 | 23.35 | B | C |
| ATOM | 204 | SG | CYS | B | 137 | 5.165 | 54.130 | 82.295 | 1.00 | 25.95 | B | S |
| ATOM | 205 | C | CYS | B | 137 | 7.703 | 51.258 | 80.793 | 1.00 | 21.73 | B | C |
| ATOM | 206 | O | CYS | B | 137 | 8.867 | 51.643 | 80.820 | 1.00 | 22.10 | B | O |
| ATOM | 207 | N | LYS | B | 138 | 7.371 | 49.974 | 80.808 | 1.00 | 22.50 | B | N |
| ATOM | 208 | CA | LYS | B | 138 | 8.388 | 48.928 | 80.846 | 1.00 | 22.69 | B | C |
| ATOM | 209 | CB | LYS | B | 138 | 7.734 | 47.557 | 81.013 | 1.00 | 27.90 | B | C |
| ATOM | 210 | CG | LYS | B | 138 | 7.553 | 47.117 | 82.449 | 1.00 | 34.51 | B | C |
| ATOM | 211 | CD | LYS | B | 138 | 6.777 | 45.814 | 82.512 | 1.00 | 40.74 | B | C |
| ATOM | 212 | CE | LYS | B | 138 | 6.342 | 45.492 | 83.934 | 1.00 | 44.64 | B | C |
| ATOM | 213 | NZ | LYS | B | 138 | 6.821 | 44.138 | 84.345 | 1.00 | 49.39 | B | N |
| ATOM | 214 | C | LYS | B | 138 | 9.204 | 48.939 | 79.558 | 1.00 | 20.20 | B | C |
| ATOM | 215 | O | LYS | B | 138 | 10.427 | 48.802 | 79.593 | 1.00 | 19.32 | B | O |
| ATOM | 216 | N | GLY | B | 139 | 8.513 | 49.093 | 78.428 | 1.00 | 18.01 | B | N |
| ATOM | 217 | CA | GLY | B | 139 | 9.174 | 49.124 | 77.134 | 1.00 | 14.57 | B | C |
| ATOM | 218 | C | GLY | B | 139 | 10.124 | 50.300 | 76.989 | 1.00 | 15.74 | B | C |
| ATOM | 219 | O | GLY | B | 139 | 11.256 | 50.143 | 76.532 | 1.00 | 13.40 | B | O |
| ATOM | 220 | N | LEU | B | 140 | 9.668 | 51.485 | 77.383 | 1.00 | 16.06 | B | N |
| ATOM | 221 | CA | LEU | B | 140 | 10.494 | 52.680 | 77.290 | 1.00 | 16.45 | B | C |
| ATOM | 222 | CB | LEU | B | 140 | 9.673 | 53.915 | 77.676 | 1.00 | 18.85 | B | C |
| ATOM | 223 | CG | LEU | B | 140 | 8.573 | 54.275 | 76.668 | 1.00 | 17.08 | B | C |
| ATOM | 224 | CD1 | LEU | B | 140 | 7.712 | 55.407 | 77.196 | 1.00 | 14.23 | B | C |
| ATOM | 225 | CD2 | LEU | B | 140 | 9.221 | 54.675 | 75.361 | 1.00 | 15.80 | B | C |
| ATOM | 226 | C | LEU | B | 140 | 11.718 | 52.559 | 78.189 | 1.00 | 17.53 | B | C |
| ATOM | 227 | O | LEU | B | 140 | 12.806 | 53.027 | 77.846 | 1.00 | 18.93 | B | O |
| ATOM | 228 | N | TYR | B | 141 | 11.545 | 51.927 | 79.344 | 1.00 | 18.55 | B | N |
| ATOM | 229 | CA | TYR | B | 141 | 12.650 | 51.752 | 80.277 | 1.00 | 16.73 | B | C |
| ATOM | 230 | CB | TYR | B | 141 | 12.141 | 51.175 | 81.603 | 1.00 | 17.76 | B | C |
| ATOM | 231 | CG | TYR | B | 141 | 13.202 | 50.466 | 82.408 | 1.00 | 18.73 | B | C |
| ATOM | 232 | CD1 | TYR | B | 141 | 13.315 | 49.076 | 82.375 | 1.00 | 15.87 | B | C |
| ATOM | 233 | CE1 | TYR | B | 141 | 14.332 | 48.422 | 83.066 | 1.00 | 20.28 | B | C |
| ATOM | 234 | CD2 | TYR | B | 141 | 14.132 | 51.187 | 83.163 | 1.00 | 19.39 | B | C |
| ATOM | 235 | CE2 | TYR | B | 141 | 15.154 | 50.546 | 83.858 | 1.00 | 18.03 | B | C |
| ATOM | 236 | CZ | TYR | B | 141 | 15.251 | 49.164 | 83.804 | 1.00 | 22.33 | B | C |
| ATOM | 237 | OH | TYR | B | 141 | 16.277 | 48.518 | 84.465 | 1.00 | 25.81 | B | O |
| ATOM | 238 | C | TYR | B | 141 | 13.683 | 50.815 | 79.659 | 1.00 | 18.12 | B | C |
| ATOM | 239 | O | TYR | B | 141 | 14.876 | 51.143 | 79.582 | 1.00 | 18.95 | B | O |
| ATOM | 240 | N | ARG | B | 142 | 13.230 | 49.649 | 79.210 | 1.00 | 16.33 | B | N |
| ATOM | 241 | CA | ARG | B | 142 | 14.141 | 48.683 | 78.614 | 1.00 | 17.79 | B | C |
| ATOM | 242 | CB | ARG | B | 142 | 13.381 | 47.411 | 78.225 | 1.00 | 16.69 | B | C |
| ATOM | 243 | CG | ARG | B | 142 | 14.094 | 46.578 | 77.188 | 1.00 | 22.51 | B | C |
| ATOM | 244 | CD | ARG | B | 142 | 13.946 | 45.073 | 77.399 | 1.00 | 24.16 | B | C |
| ATOM | 245 | NE | ARG | B | 142 | 14.960 | 44.357 | 76.621 | 1.00 | 28.28 | B | N |
| ATOM | 246 | CZ | ARG | B | 142 | 14.747 | 43.222 | 75.958 | 1.00 | 29.13 | B | C |
| ATOM | 247 | NH1 | ARG | B | 142 | 13.544 | 42.662 | 75.974 | 1.00 | 29.22 | B | N |
| ATOM | 248 | NH2 | ARG | B | 142 | 15.732 | 42.659 | 75.261 | 1.00 | 20.61 | B | N |
| ATOM | 249 | C | ARG | B | 142 | 14.857 | 49.276 | 77.395 | 1.00 | 19.46 | B | C |
| ATOM | 250 | O | ARG | B | 142 | 16.029 | 48.988 | 77.157 | 1.00 | 18.56 | B | O |
| ATOM | 251 | N | ALA | B | 143 | 14.158 | 50.115 | 76.635 | 1.00 | 19.10 | B | N |
| ATOM | 252 | CA | ALA | B | 143 | 14.745 | 50.735 | 75.448 | 1.00 | 16.31 | B | C |
| ATOM | 253 | CB | ALA | B | 143 | 13.682 | 51.512 | 74.669 | 1.00 | 16.16 | B | C |
| ATOM | 254 | C | ALA | B | 143 | 15.886 | 51.657 | 75.816 | 1.00 | 14.38 | B | C |
| ATOM | 255 | O | ALA | B | 143 | 16.898 | 51.708 | 75.121 | 1.00 | 12.75 | B | O |
| ATOM | 256 | N | LEU | B | 144 | 15.722 | 52.394 | 76.911 | 1.00 | 16.37 | B | N |
| ATOM | 257 | CA | LEU | B | 144 | 16.759 | 53.317 | 77.369 | 1.00 | 14.12 | B | C |
| ATOM | 258 | CB | LEU | B | 144 | 16.197 | 54.262 | 78.425 | 1.00 | 14.27 | B | C |
| ATOM | 259 | CG | LEU | B | 144 | 15.359 | 55.410 | 77.875 | 1.00 | 17.14 | B | C |
| ATOM | 260 | CD1 | LEU | B | 144 | 14.683 | 56.168 | 79.008 | 1.00 | 11.98 | B | C |
| ATOM | 261 | CD2 | LEU | B | 144 | 16.262 | 56.325 | 77.078 | 1.00 | 18.43 | B | C |
| ATOM | 262 | C | LEU | B | 144 | 17.925 | 52.533 | 77.950 | 1.00 | 13.64 | B | C |
| ATOM | 263 | O | LEU | B | 144 | 19.067 | 52.979 | 77.923 | 1.00 | 12.92 | B | O |
| ATOM | 264 | N | CYS | B | 145 | 17.621 | 51.355 | 78.479 | 1.00 | 14.98 | B | N |
| ATOM | 265 | CA | CYS | B | 145 | 18.636 | 50.490 | 79.060 | 1.00 | 19.73 | B | C |
| ATOM | 266 | CB | CYS | B | 145 | 17.977 | 49.320 | 79.786 | 1.00 | 25.56 | B | C |
| ATOM | 267 | SG | CYS | B | 145 | 17.926 | 49.519 | 81.554 | 1.00 | 35.22 | B | S |
| ATOM | 268 | C | CYS | B | 145 | 19.532 | 49.940 | 77.976 | 1.00 | 15.77 | B | C |
| ATOM | 269 | O | CYS | B | 145 | 20.741 | 49.787 | 78.173 | 1.00 | 18.34 | B | O |
| ATOM | 270 | N | ILE | B | 146 | 18.921 | 49.621 | 76.840 | 1.00 | 14.48 | B | N |
| ATOM | 271 | CA | ILE | B | 146 | 19.641 | 49.076 | 75.698 | 1.00 | 12.17 | B | C |
| ATOM | 272 | CB | ILE | B | 146 | 18.667 | 48.613 | 74.603 | 1.00 | 9.36 | B | C |
| ATOM | 273 | CG2 | ILE | B | 146 | 19.410 | 48.387 | 73.301 | 1.00 | 11.59 | B | C |
| ATOM | 274 | CG1 | ILE | B | 146 | 17.981 | 47.321 | 75.041 | 1.00 | 8.97 | B | C |
| ATOM | 275 | CD1 | ILE | B | 146 | 16.664 | 47.055 | 74.341 | 1.00 | 10.22 | B | C |
| ATOM | 276 | C | ILE | B | 146 | 20.613 | 50.098 | 75.115 | 1.00 | 12.86 | B | C |
| ATOM | 277 | O | ILE | B | 146 | 21.766 | 49.765 | 74.827 | 1.00 | 13.75 | B | O |
| ATOM | 278 | N | ARG | B | 147 | 20.171 | 51.343 | 74.953 | 1.00 | 10.75 | B | N |
| ATOM | 279 | CA | ARG | B | 147 | 21.061 | 52.351 | 74.394 | 1.00 | 9.54 | B | C |
| ATOM | 280 | CB | ARG | B | 147 | 20.323 | 53.659 | 74.119 | 1.00 | 6.23 | B | C |
| ATOM | 281 | CG | ARG | B | 147 | 21.284 | 54.781 | 73.748 | 1.00 | 4.46 | B | C |
| ATOM | 282 | CD | ARG | B | 147 | 20.594 | 55.962 | 73.095 | 1.00 | 6.95 | B | C |
| ATOM | 283 | NE | ARG | B | 147 | 21.551 | 57.015 | 72.736 | 1.00 | 10.68 | B | N |
| ATOM | 284 | CZ | ARG | B | 147 | 22.324 | 56.986 | 71.652 | 1.00 | 10.96 | B | C |
| ATOM | 285 | NH1 | ARG | B | 147 | 22.259 | 55.955 | 70.819 | 1.00 | 7.25 | B | N |
| ATOM | 286 | NH2 | ARG | B | 147 | 23.151 | 57.991 | 71.393 | 1.00 | 7.25 | B | N |
| ATOM | 287 | C | ARG | B | 147 | 22.226 | 52.626 | 75.331 | 1.00 | 12.37 | B | C |
| ATOM | 288 | O | ARG | B | 147 | 23.362 | 52.832 | 74.888 | 1.00 | 15.42 | B | O |
| ATOM | 289 | N | GLU | B | 148 | 21.947 | 52.645 | 76.628 | 1.00 | 13.14 | B | N |
| ATOM | 290 | CA | GLU | B | 148 | 22.991 | 52.894 | 77.610 | 1.00 | 12.99 | B | C |
| ATOM | 291 | CB | GLU | B | 148 | 22.376 | 53.014 | 79.004 | 1.00 | 17.43 | B | C |
| ATOM | 292 | CG | GLU | B | 148 | 23.402 | 53.182 | 80.122 | 1.00 | 20.15 | B | C |
| ATOM | 293 | CD | GLU | B | 148 | 22.803 | 52.930 | 81.487 | 1.00 | 22.89 | B | C |
| ATOM | 294 | OE1 | GLU | B | 148 | 22.834 | 53.853 | 82.331 | 1.00 | 25.07 | B | O |
| ATOM | 295 | OE2 | GLU | B | 148 | 22.296 | 51.812 | 81.716 | 1.00 | 22.18 | B | O |
| ATOM | 296 | C | GLU | B | 148 | 24.015 | 51.764 | 77.599 | 1.00 | 12.57 | B | C |
| ATOM | 297 | O | GLU | B | 148 | 25.222 | 52.002 | 77.660 | 1.00 | 12.36 | B | O |
| ATOM | 298 | N | LYS | B | 149 | 23.529 | 50.528 | 77.520 | 1.00 | 10.62 | B | N |
| ATOM | 299 | CA | LYS | B | 149 | 24.413 | 49.371 | 77.508 | 1.00 | 11.48 | B | C |
| ATOM | 300 | CB | LYS | B | 149 | 23.587 | 48.080 | 77.442 | 1.00 | 9.03 | B | C |
| ATOM | 301 | CG | LYS | B | 149 | 24.426 | 46.809 | 77.392 | 1.00 | 6.74 | B | C |
| ATOM | 302 | CD | LYS | B | 149 | 23.560 | 45.567 | 77.425 | 1.00 | 7.01 | B | C |
| ATOM | 303 | CE | LYS | B | 149 | 22.725 | 45.431 | 76.158 | 1.00 | 10.39 | B | C |
| ATOM | 304 | NZ | LYS | B | 149 | 21.900 | 44.190 | 76.164 | 1.00 | 13.70 | B | N |
| ATOM | 305 | C | LYS | B | 149 | 25.410 | 49.416 | 76.351 | 1.00 | 13.42 | B | C |
| ATOM | 306 | O | LYS | B | 149 | 26.615 | 49.262 | 76.553 | 1.00 | 14.70 | B | O |
| ATOM | 307 | N | TYR | B | 150 | 24.906 | 49.642 | 75.140 | 1.00 | 14.98 | B | N |
| ATOM | 308 | CA | TYR | B | 150 | 25.751 | 49.697 | 73.957 | 1.00 | 12.28 | B | C |
| ATOM | 309 | CB | TYR | B | 150 | 24.878 | 49.562 | 72.708 | 1.00 | 16.29 | B | C |
| ATOM | 310 | CG | TYR | B | 150 | 24.276 | 48.173 | 72.568 | 1.00 | 17.60 | B | C |
| ATOM | 311 | CD1 | TYR | B | 150 | 25.074 | 47.085 | 72.213 | 1.00 | 18.40 | B | C |
| ATOM | 312 | CE1 | TYR | B | 150 | 24.553 | 45.788 | 72.157 | 1.00 | 16.75 | B | C |
| ATOM | 313 | CD2 | TYR | B | 150 | 22.934 | 47.932 | 72.859 | 1.00 | 15.23 | B | C |
| ATOM | 314 | CE2 | TYR | B | 150 | 22.404 | 46.636 | 72.805 | 1.00 | 16.42 | B | C |
| ATOM | 315 | CZ | TYR | B | 150 | 23.227 | 45.570 | 72.455 | 1.00 | 16.36 | B | C |
| ATOM | 316 | OH | TYR | B | 150 | 22.739 | 44.283 | 72.414 | 1.00 | 16.17 | B | O |
| ATOM | 317 | C | TYR | B | 150 | 26.612 | 50.954 | 73.886 | 1.00 | 14.67 | B | C |
| ATOM | 318 | O | TYR | B | 150 | 27.685 | 50.951 | 73.268 | 1.00 | 14.64 | B | O |
| ATOM | 319 | N | MET | B | 151 | 26.170 | 52.034 | 74.522 | 1.00 | 14.35 | B | N |
| ATOM | 320 | CA | MET | B | 151 | 26.964 | 53.264 | 74.511 | 1.00 | 16.43 | B | C |
| ATOM | 321 | CB | MET | B | 151 | 26.122 | 54.459 | 74.967 | 1.00 | 16.12 | B | C |
| ATOM | 322 | CG | MET | B | 151 | 25.107 | 54.958 | 73.941 | 1.00 | 16.36 | B | C |
| ATOM | 323 | SD | MET | B | 151 | 25.837 | 55.459 | 72.353 | 1.00 | 14.40 | B | S |
| ATOM | 324 | CE | MET | B | 151 | 25.428 | 54.056 | 71.366 | 1.00 | 6.89 | B | C |
| ATOM | 325 | C | MET | B | 151 | 28.203 | 53.161 | 75.404 | 1.00 | 18.53 | B | C |
| ATOM | 326 | O | MET | B | 151 | 29.302 | 53.527 | 74.991 | 1.00 | 22.35 | B | O |
| ATOM | 327 | N | LEU | B | 152 | 28.032 | 52.671 | 76.629 | 1.00 | 21.36 | B | N |
| ATOM | 328 | CA | LEU | B | 152 | 29.160 | 52.548 | 77.558 | 1.00 | 21.82 | B | C |
| ATOM | 329 | CB | LEU | B | 152 | 28.660 | 52.256 | 78.973 | 1.00 | 23.08 | B | C |
| ATOM | 330 | CC | LEU | B | 152 | 27.623 | 53.213 | 79.569 | 1.00 | 26.47 | B | C |
| ATOM | 331 | CD1 | LEU | B | 152 | 27.400 | 52.839 | 81.026 | 1.00 | 22.85 | B | C |
| ATOM | 332 | CD2 | LEU | B | 152 | 28.092 | 54.674 | 79.437 | 1.00 | 22.69 | B | C |
| ATOM | 333 | C | LEU | B | 152 | 30.111 | 51.446 | 77.136 | 1.00 | 18.61 | B | C |
| ATOM | 334 | O | LEU | B | 152 | 31.325 | 51.558 | 77.295 | 1.00 | 18.23 | B | O |
| ATOM | 335 | N | LYS | B | 153 | 29.540 | 50.378 | 76.600 | 1.00 | 18.04 | B | N |
| ATOM | 336 | CA | LYS | B | 153 | 30.306 | 49.233 | 76.149 | 1.00 | 17.87 | B | C |
| ATOM | 337 | CB | LYS | B | 153 | 29.331 | 48.129 | 75.736 | 1.00 | 19.68 | B | C |
| ATOM | 338 | CG | LYS | B | 153 | 29.918 | 47.007 | 74.927 | 1.00 | 23.62 | B | C |
| ATOM | 339 | CD | LYS | B | 153 | 28.809 | 46.142 | 74.368 | 1.00 | 25.67 | B | C |
| ATOM | 340 | CE | LYS | B | 153 | 27.960 | 45.574 | 75.481 | 1.00 | 27.89 | B | C |
| ATOM | 341 | NZ | LYS | B | 153 | 26.976 | 44.585 | 74.968 | 1.00 | 34.82 | B | N |
| ATOM | 342 | C | LYS | B | 153 | 31.248 | 49.593 | 74.995 | 1.00 | 18.23 | B | C |
| ATOM | 343 | O | LYS | B | 153 | 32.241 | 48.904 | 74.767 | 1.00 | 21.45 | B | O |
| ATOM | 344 | N | SER | B | 154 | 30.950 | 50.676 | 74.282 | 1.00 | 16.45 | B | N |
| ATOM | 345 | CA | SER | B | 154 | 31.782 | 51.099 | 73.157 | 1.00 | 17.83 | B | C |
| ATOM | 346 | CB | SER | B | 154 | 30.949 | 51.196 | 71.877 | 1.00 | 17.45 | B | C |
| ATOM | 347 | OG | SER | B | 154 | 29.969 | 52.210 | 71.997 | 1.00 | 22.10 | B | O |
| ATOM | 348 | C | SER | B | 154 | 32.468 | 52.431 | 73.405 | 1.00 | 18.25 | B | C |
| ATOM | 349 | O | SER | B | 154 | 33.068 | 53.008 | 72.498 | 1.00 | 19.05 | B | O |
| ATOM | 350 | N | PHE | B | 155 | 32.371 | 52.918 | 74.636 | 1.00 | 17.91 | B | N |
| ATOM | 351 | CA | PHE | B | 155 | 32.994 | 54.177 | 75.030 | 1.00 | 17.30 | B | C |
| ATOM | 352 | CB | PHE | B | 155 | 34.501 | 54.106 | 74.796 | 1.00 | 20.86 | B | C |
| ATOM | 353 | CG | PHE | B | 155 | 35.179 | 53.055 | 75.620 | 1.00 | 24.23 | B | C |
| ATOM | 354 | CD1 | PHE | B | 155 | 35.650 | 53.354 | 76.891 | 1.00 | 26.29 | B | C |
| ATOM | 355 | CD2 | PHE | B | 155 | 35.286 | 51.748 | 75.155 | 1.00 | 24.68 | B | C |
| ATOM | 356 | CE1 | PHE | B | 155 | 36.212 | 52.364 | 77.694 | 1.00 | 27.90 | B | C |
| ATOM | 357 | CE2 | PHE | B | 155 | 35.845 | 50.748 | 75.949 | 1.00 | 25.33 | B | C |
| ATOM | 358 | CZ | PHE | B | 155 | 36.307 | 51.057 | 77.221 | 1.00 | 26.67 | B | C |
| ATOM | 359 | C | PHE | B | 155 | 32.412 | 55.394 | 74.331 | 1.00 | 17.79 | B | C |
| ATOM | 360 | O | PHE | B | 155 | 33.130 | 56.341 | 73.990 | 1.00 | 16.86 | B | O |
| ATOM | 361 | N | GLN | B | 156 | 31.102 | 55.367 | 74.119 | 1.00 | 16.08 | B | N |
| ATOM | 362 | CA | GLN | B | 156 | 30.434 | 56.490 | 73.490 | 1.00 | 16.03 | B | C |
| ATOM | 363 | CB | GLN | B | 156 | 29.580 | 55.999 | 72.321 | 1.00 | 15.61 | B | C |
| ATOM | 364 | CG | GLN | B | 156 | 30.437 | 55.500 | 71.143 | 1.00 | 11.78 | B | C |
| ATOM | 365 | CD | GLN | B | 156 | 29.653 | 55.348 | 69.863 | 1.00 | 11.82 | B | C |
| ATOM | 366 | OE1 | GLN | B | 156 | 29.044 | 54.308 | 69.615 | 1.00 | 12.74 | B | O |
| ATOM | 367 | NE2 | GLN | B | 156 | 29.659 | 56.389 | 69.039 | 1.00 | 8.83 | B | N |
| ATOM | 368 | C | GLN | B | 156 | 29.607 | 57.160 | 74.576 | 1.00 | 15.57 | B | C |
| ATOM | 369 | O | GLN | B | 156 | 29.425 | 56.587 | 75.650 | 1.00 | 16.98 | B | O |
| ATOM | 370 | N | ARG | B | 157 | 29.114 | 58.363 | 74.309 | 1.00 | 13.67 | B | N |
| ATOM | 371 | CA | ARG | B | 157 | 28.366 | 59.116 | 75.311 | 1.00 | 13.70 | B | C |
| ATOM | 372 | CB | ARG | B | 157 | 28.514 | 60.615 | 75.024 | 1.00 | 10.33 | B | C |
| ATOM | 373 | CG | ARG | B | 157 | 29.954 | 61.036 | 74.747 | 1.00 | 15.05 | B | C |
| ATOM | 374 | CD | ARG | B | 157 | 30.052 | 62.468 | 74.238 | 1.00 | 15.27 | B | C |
| ATOM | 375 | NE | ARG | B | 157 | 29.557 | 62.588 | 72.867 | 1.00 | 20.35 | B | N |
| ATOM | 376 | CZ | ARG | B | 157 | 29.531 | 63.722 | 72.170 | 1.00 | 17.76 | B | C |
| ATOM | 377 | NH1 | ARG | B | 157 | 29.058 | 63.723 | 70.932 | 1.00 | 19.30 | B | N |
| ATOM | 378 | NH2 | ARG | B | 157 | 29.983 | 64.851 | 72.701 | 1.00 | 11.43 | B | N |
| ATOM | 379 | C | ARG | B | 157 | 26.893 | 58.803 | 75.547 | 1.00 | 13.86 | B | C |
| ATOM | 380 | O | ARG | B | 157 | 26.151 | 58.490 | 74.624 | 1.00 | 17.89 | B | O |
| ATOM | 381 | N | PHE | B | 158 | 26.497 | 58.894 | 76.816 | 1.00 | 15.57 | B | N |
| ATOM | 382 | CA | PHE | B | 158 | 25.119 | 58.707 | 77.271 | 1.00 | 13.94 | B | C |
| ATOM | 383 | CB | PHE | B | 158 | 24.859 | 57.275 | 77.707 | 1.00 | 11.36 | B | C |
| ATOM | 384 | CG | PHE | B | 158 | 23.399 | 56.969 | 77.879 | 1.00 | 13.13 | B | C |
| ATOM | 385 | CD1 | PHE | B | 158 | 22.831 | 56.879 | 79.146 | 1.00 | 11.45 | B | C |
| ATOM | 386 | CD2 | PHE | B | 158 | 22.581 | 56.820 | 76.771 | 1.00 | 8.46 | B | C |
| ATOM | 387 | CE1 | PHE | B | 158 | 21.470 | 56.650 | 79.308 | 1.00 | 7.76 | B | C |
| ATOM | 388 | CE2 | PHE | B | 158 | 21.228 | 56.592 | 76.921 | 1.00 | 11.98 | B | C |
| ATOM | 389 | CZ | PHE | B | 158 | 20.668 | 56.508 | 78.197 | 1.00 | 12.90 | B | C |
| ATOM | 390 | C | PHE | B | 158 | 24.951 | 59.647 | 78.472 | 1.00 | 16.09 | B | C |
| ATOM | 391 | O | PHE | B | 158 | 25.702 | 59.548 | 79.445 | 1.00 | 16.57 | B | O |
| ATOM | 392 | N | PRO | B | 159 | 23.964 | 60.570 | 78.420 | 1.00 | 16.69 | B | N |
| ATOM | 393 | CD | PRO | B | 159 | 22.993 | 60.711 | 77.324 | 1.00 | 14.40 | B | C |
| ATOM | 394 | CA | PRO | B | 159 | 23.697 | 61.542 | 79.491 | 1.00 | 16.08 | B | C |
| ATOM | 395 | CB | PRO | B | 159 | 22.455 | 62.291 | 79.001 | 1.00 | 13.30 | B | C |
| ATOM | 396 | CG | PRO | B | 159 | 21.845 | 61.384 | 77.997 | 1.00 | 15.10 | B | C |
| ATOM | 397 | C | PRO | B | 159 | 23.496 | 60.957 | 80.885 | 1.00 | 14.94 | B | C |
| ATOM | 398 | O | PRO | B | 159 | 22.950 | 59.870 | 81.040 | 1.00 | 17.89 | B | O |
| ATOM | 399 | N | LYS | B | 160 | 23.924 | 61.709 | 81.894 | 1.00 | 16.71 | B | N |
| ATOM | 400 | CA | LYS | B | 160 | 23.816 | 61.283 | 83.287 | 1.00 | 18.58 | B | C |
| ATOM | 401 | CB | LYS | B | 160 | 24.642 | 62.207 | 84.188 | 1.00 | 17.41 | B | C |
| ATOM | 402 | CG | LYS | B | 160 | 26.144 | 61.968 | 84.096 | 1.00 | 26.52 | B | C |
| ATOM | 403 | CD | LYS | B | 160 | 26.953 | 63.071 | 84.778 | 1.00 | 30.88 | B | C |
| ATOM | 404 | CE | LYS | B | 160 | 26.588 | 64.466 | 84.256 | 1.00 | 36.82 | B | C |
| ATOM | 405 | NZ | LYS | B | 160 | 26.887 | 64.653 | 82.800 | 1.00 | 37.96 | B | N |
| ATOM | 406 | C | LYS | B | 160 | 22.399 | 61.204 | 83.836 | 1.00 | 17.17 | B | C |
| ATOM | 407 | O | LYS | B | 160 | 22.021 | 60.196 | 84.430 | 1.00 | 16.39 | B | O |
| ATOM | 408 | N | THR | B | 161 | 21.602 | 62.248 | 83.629 | 1.00 | 18.15 | B | N |
| ATOM | 409 | CA | THR | B | 161 | 20.254 | 62.246 | 84.184 | 1.00 | 19.58 | B | C |
| ATOM | 410 | CB | THR | B | 161 | 19.522 | 63.593 | 83.928 | 1.00 | 18.86 | B | C |
| ATOM | 411 | OG1 | THR | B | 161 | 18.664 | 63.482 | 82.794 | 1.00 | 28.69 | B | O |
| ATOM | 412 | CG2 | THR | B | 161 | 20.521 | 64.708 | 83.713 | 1.00 | 15.63 | B | C |
| ATOM | 413 | C | THR | B | 161 | 19.376 | 61.056 | 83.798 | 1.00 | 19.31 | B | C |
| ATOM | 414 | O | THR | B | 161 | 18.705 | 60.496 | 84.660 | 1.00 | 21.41 | B | O |
| ATOM | 415 | N | PRO | B | 162 | 19.356 | 60.650 | 82.514 | 1.00 | 20.44 | B | N |
| ATOM | 416 | CD | PRO | B | 162 | 20.017 | 61.200 | 81.322 | 1.00 | 20.84 | B | C |
| ATOM | 417 | CA | PRO | B | 162 | 18.513 | 59.491 | 82.176 | 1.00 | 20.33 | B | C |
| ATOM | 418 | CB | PRO | B | 162 | 18.675 | 59.345 | 80.662 | 1.00 | 16.38 | B | C |
| ATOM | 419 | CG | PRO | B | 162 | 19.186 | 60.646 | 80.204 | 1.00 | 19.95 | B | C |
| ATOM | 420 | C | PRO | B | 162 | 18.981 | 58.233 | 82.915 | 1.00 | 20.25 | B | C |
| ATOM | 421 | O | PRO | B | 162 | 18.194 | 57.324 | 83.178 | 1.00 | 19.89 | B | O |
| ATOM | 422 | N | SER | B | 163 | 20.272 | 58.187 | 83.233 | 1.00 | 20.15 | B | N |
| ATOM | 423 | CA | SER | B | 163 | 20.856 | 57.052 | 83.941 | 1.00 | 22.09 | B | C |
| ATOM | 424 | CB | SER | B | 163 | 22.381 | 57.113 | 83.859 | 1.00 | 23.93 | B | C |
| ATOM | 425 | OG | SER | B | 163 | 22.838 | 56.635 | 82.601 | 1.00 | 26.00 | B | O |
| ATOM | 426 | C | SER | B | 163 | 20.420 | 57.047 | 85.400 | 1.00 | 21.41 | B | C |
| ATOM | 427 | O | SER | B | 163 | 20.058 | 56.004 | 85.948 | 1.00 | 22.86 | B | O |
| ATOM | 428 | N | LYS | B | 164 | 20.460 | 58.216 | 86.028 | 1.00 | 17.68 | B | N |
| ATOM | 429 | CA | LYS | B | 164 | 20.043 | 58.334 | 87.414 | 1.00 | 17.58 | B | C |
| ATOM | 430 | CB | LYS | B | 164 | 20.054 | 59.795 | 87.847 | 1.00 | 16.11 | B | C |
| ATOM | 431 | CG | LYS | B | 164 | 21.446 | 60.347 | 88.098 | 1.00 | 19.36 | B | C |
| ATOM | 432 | CD | LYS | B | 164 | 21.394 | 61.844 | 88.349 | 1.00 | 20.33 | B | C |
| ATOM | 433 | CE | LYS | B | 164 | 22.785 | 62.415 | 88.523 | 1.00 | 26.06 | B | C |
| ATOM | 434 | NZ | LYS | B | 164 | 22.757 | 63.906 | 88.548 | 1.00 | 32.59 | B | N |
| ATOM | 435 | C | LYS | B | 164 | 18.643 | 57.756 | 87.598 | 1.00 | 19.21 | B | C |
| ATOM | 436 | O | LYS | B | 164 | 18.384 | 57.061 | 88.584 | 1.00 | 21.80 | B | O |
| ATOM | 437 | N | TYR | B | 165 | 17.742 | 58.035 | 86.654 | 1.00 | 17.58 | B | N |
| ATOM | 438 | CA | TYR | B | 165 | 16.375 | 57.528 | 86.743 | 1.00 | 17.92 | B | C |
| ATOM | 439 | CB | TYR | B | 165 | 15.481 | 58.194 | 85.698 | 1.00 | 17.07 | B | C |
| ATOM | 440 | CG | TYR | B | 165 | 14.852 | 59.470 | 86.182 | 1.00 | 16.98 | B | C |
| ATOM | 441 | CD1 | TYR | B | 165 | 13.663 | 59.451 | 86.905 | 1.00 | 18.60 | B | C |
| ATOM | 442 | CE1 | TYR | B | 165 | 13.103 | 60.622 | 87.399 | 1.00 | 19.43 | B | C |
| ATOM | 443 | CD2 | TYR | B | 165 | 15.466 | 60.697 | 85.955 | 1.00 | 18.81 | B | C |
| ATOM | 444 | CE2 | TYR | B | 165 | 14.917 | 61.882 | 86.442 | 1.00 | 20.10 | B | C |
| ATOM | 445 | CZ | TYR | B | 165 | 13.736 | 61.838 | 87.167 | 1.00 | 21.44 | B | C |
| ATOM | 446 | OH | TYR | B | 165 | 13.203 | 63.004 | 87.683 | 1.00 | 23.25 | B | O |
| ATOM | 447 | C | TYR | B | 165 | 16.346 | 56.022 | 86.543 | 1.00 | 20.46 | B | C |
| ATOM | 448 | O | TYR | B | 165 | 15.541 | 55.317 | 87.156 | 1.00 | 22.53 | B | O |
| ATOM | 449 | N | LEU | B | 166 | 17.228 | 55.530 | 85.679 | 1.00 | 20.53 | B | N |
| ATOM | 450 | CA | LEU | B | 166 | 17.298 | 54.104 | 85.403 | 1.00 | 21.59 | B | C |
| ATOM | 451 | CB | LEU | B | 166 | 18.288 | 53.833 | 84.262 | 1.00 | 22.86 | B | C |
| ATOM | 452 | CG | LEU | B | 166 | 17.852 | 54.189 | 82.829 | 1.00 | 22.35 | B | C |
| ATOM | 453 | CD1 | LEU | B | 166 | 18.958 | 53.816 | 81.853 | 1.00 | 18.72 | B | C |
| ATOM | 454 | CD2 | LEU | B | 166 | 16.569 | 53.455 | 82.469 | 1.00 | 18.76 | B | C |
| ATOM | 455 | C | LEU | B | 166 | 17.732 | 53.360 | 86.661 | 1.00 | 20.68 | B | C |
| ATOM | 456 | O | LEU | B | 166 | 17.118 | 52.364 | 87.045 | 1.00 | 19.81 | B | O |
| ATOM | 457 | N | ARG | B | 167 | 18.793 | 53.846 | 87.301 | 1.00 | 21.82 | B | N |
| ATOM | 458 | CA | ARG | B | 167 | 19.300 | 53.219 | 88.518 | 1.00 | 21.84 | B | C |
| ATOM | 459 | CB | ARG | B | 167 | 20.538 | 53.970 | 89.024 | 1.00 | 21.19 | B | C |
| ATOM | 460 | CG | ARG | B | 167 | 21.798 | 53.788 | 88.163 | 1.00 | 18.78 | B | C |
| ATOM | 461 | CD | ARG | B | 167 | 22.114 | 52.314 | 87.870 | 1.00 | 18.71 | B | C |
| ATOM | 462 | NE | ARG | B | 167 | 21.392 | 51.796 | 86.699 | 1.00 | 23.87 | B | N |
| ATOM | 463 | CZ | ARG | B | 167 | 21.658 | 52.116 | 85.428 | 1.00 | 19.86 | B | C |
| ATOM | 464 | NH1 | ARG | B | 167 | 22.640 | 52.960 | 85.132 | 1.00 | 17.39 | B | N |
| ATOM | 465 | NH2 | ARG | B | 167 | 20.924 | 51.606 | 84.448 | 1.00 | 13.96 | B | N |
| ATOM | 466 | C | ARG | B | 167 | 18.201 | 53.210 | 89.585 | 1.00 | 23.67 | B | C |
| ATOM | 467 | O | ARG | B | 167 | 17.977 | 52.192 | 90.244 | 1.00 | 23.02 | B | O |
| ATOM | 468 | N | SER | B | 168 | 17.508 | 54.339 | 89.735 | 1.00 | 24.05 | B | N |
| ATOM | 469 | CA | SER | B | 168 | 16.415 | 54.459 | 90.701 | 1.00 | 25.43 | B | C |
| ATOM | 470 | CB | SER | B | 168 | 15.712 | 55.801 | 90.557 | 1.00 | 26.18 | B | C |
| ATOM | 471 | OG | SER | B | 168 | 16.632 | 56.870 | 90.654 | 1.00 | 36.80 | B | O |
| ATOM | 472 | C | SER | B | 168 | 15.384 | 53.380 | 90.465 | 1.00 | 26.89 | B | C |
| ATOM | 473 | O | SER | B | 168 | 15.025 | 52.628 | 91.372 | 1.00 | 29.97 | B | O |
| ATOM | 474 | N | ILE | B | 169 | 14.891 | 53.330 | 89.234 | 1.00 | 27.18 | B | N |
| ATOM | 475 | CA | ILE | B | 169 | 13.886 | 52.357 | 88.850 | 1.00 | 27.08 | B | C |
| ATOM | 476 | CB | ILE | B | 169 | 13.599 | 52.439 | 87.334 | 1.00 | 26.15 | B | C |
| ATOM | 477 | CG2 | ILE | B | 169 | 12.815 | 51.219 | 86.876 | 1.00 | 26.22 | B | C |
| ATOM | 478 | CG1 | ILE | B | 169 | 12.827 | 53.731 | 87.033 | 1.00 | 27.87 | B | C |
| ATOM | 479 | CD1 | ILE | B | 169 | 12.305 | 53.840 | 85.613 | 1.00 | 25.86 | B | C |
| ATOM | 480 | C | ILE | B | 169 | 14.339 | 50.956 | 89.215 | 1.00 | 28.25 | B | C |
| ATOM | 481 | O | ILE | B | 169 | 13.532 | 50.122 | 89.619 | 1.00 | 30.07 | B | O |
| ATOM | 482 | N | GLU | B | 170 | 15.637 | 50.708 | 89.089 | 1.00 | 31.29 | B | N |
| ATOM | 483 | CA | GLU | B | 170 | 16.202 | 49.398 | 89.396 | 1.00 | 34.11 | B | C |
| ATOM | 484 | CB | GLU | B | 170 | 17.578 | 49.256 | 88.750 | 1.00 | 34.11 | B | C |
| ATOM | 485 | CG | GLU | B | 170 | 17.530 | 48.975 | 87.268 | 1.00 | 37.25 | B | C |
| ATOM | 486 | CD | GLU | B | 170 | 18.784 | 49.432 | 86.559 | 1.00 | 38.69 | B | C |
| ATOM | 487 | OE1 | GLU | B | 170 | 18.708 | 49.712 | 85.341 | 1.00 | 39.55 | B | O |
| ATOM | 488 | OE2 | GLU | B | 170 | 19.844 | 49.511 | 87.221 | 1.00 | 38.11 | B | O |
| ATOM | 489 | C | GLU | B | 170 | 16.331 | 49.146 | 90.892 | 1.00 | 36.13 | B | C |
| ATOM | 490 | O | GLU | B | 170 | 16.389 | 47.998 | 91.333 | 1.00 | 36.91 | B | O |
| ATOM | 491 | N | GLY | B | 171 | 16.379 | 50.218 | 91.672 | 1.00 | 37.48 | B | N |
| ATOM | 492 | CA | GLY | B | 171 | 16.510 | 50.068 | 93.106 | 1.00 | 38.96 | B | C |
| ATOM | 493 | C | GLY | B | 171 | 17.957 | 50.138 | 93.559 | 1.00 | 40.79 | B | C |
| ATOM | 494 | O | GLY | B | 171 | 18.303 | 49.659 | 94.641 | 1.00 | 42.49 | B | O |
| ATOM | 495 | N | THR | B | 172 | 18.811 | 50.730 | 92.732 | 1.00 | 42.23 | B | N |
| ATOM | 496 | CA | THR | B | 172 | 20.216 | 50.863 | 93.080 | 1.00 | 44.66 | B | C |
| ATOM | 497 | CB | THR | B | 172 | 21.136 | 50.186 | 92.030 | 1.00 | 44.99 | B | C |
| ATOM | 498 | OG1 | THR | B | 172 | 21.849 | 51.188 | 91.297 | 1.00 | 47.97 | B | O |
| ATOM | 499 | CG2 | THR | B | 172 | 20.326 | 49.336 | 91.065 | 1.00 | 45.50 | B | C |
| ATOM | 500 | C | THR | B | 172 | 20.584 | 52.338 | 93.204 | 1.00 | 46.31 | B | C |
| ATOM | 501 | O | THR | B | 172 | 19.896 | 53.208 | 92.669 | 1.00 | 46.95 | B | O |
| ATOM | 502 | N | ALA | B | 173 | 21.661 | 52.617 | 93.930 | 1.00 | 50.19 | B | N |
| ATOM | 503 | CA | ALA | B | 173 | 22.120 | 53.989 | 94.123 | 1.00 | 51.89 | B | C |
| ATOM | 504 | CB | ALA | B | 173 | 22.932 | 54.092 | 95.406 | 1.00 | 51.99 | B | C |
| ATOM | 505 | C | ALA | B | 173 | 22.969 | 54.386 | 92.921 | 1.00 | 52.66 | B | C |
| ATOM | 506 | O | ALA | B | 173 | 23.646 | 53.543 | 92.327 | 1.00 | 53.44 | B | O |
| ATOM | 507 | N | TRP | B | 174 | 22.938 | 55.666 | 92.564 | 1.00 | 52.35 | B | N |
| ATOM | 508 | CA | TRP | B | 174 | 23.695 | 56.135 | 91.411 | 1.00 | 52.48 | B | C |
| ATOM | 509 | CB | TRP | B | 174 | 23.076 | 57.421 | 90.857 | 1.00 | 50.28 | B | C |
| ATOM | 510 | CG | TRP | B | 174 | 23.746 | 57.889 | 89.602 | 1.00 | 48.52 | B | C |
| ATOM | 511 | CD2 | TRP | B | 174 | 24.572 | 59.046 | 89.460 | 1.00 | 48.64 | B | C |
| ATOM | 512 | CE2 | TRP | B | 174 | 25.028 | 59.073 | 88.120 | 1.00 | 47.35 | B | C |
| ATOM | 513 | CE3 | TRP | B | 174 | 24.975 | 60.066 | 90.336 | 1.00 | 47.51 | B | C |
| ATOM | 514 | CD1 | TRP | B | 174 | 23.731 | 57.274 | 88.376 | 1.00 | 47.22 | B | C |
| ATOM | 515 | NE1 | TRP | B | 174 | 24.501 | 57.979 | 87.483 | 1.00 | 43.78 | B | N |
| ATOM | 516 | CZ2 | TRP | B | 174 | 25.868 | 60.081 | 87.635 | 1.00 | 48.95 | B | C |
| ATOM | 517 | CZ3 | TRP | B | 174 | 25.810 | 61.072 | 89.853 | 1.00 | 49.56 | B | C |
| ATOM | 518 | CH2 | TRP | B | 174 | 26.250 | 61.068 | 88.513 | 1.00 | 50.37 | B | C |
| ATOM | 519 | C | TRP | B | 174 | 25.184 | 56.351 | 91.665 | 1.00 | 52.34 | B | C |
| ATOM | 520 | O | TRP | B | 174 | 25.582 | 57.044 | 92.602 | 1.00 | 52.52 | B | O |
| ATOM | 521 | N | LYS | B | 175 | 25.998 | 55.757 | 90.798 | 1.00 | 54.06 | B | N |
| ATOM | 522 | CA | LYS | B | 175 | 27.453 | 55.851 | 90.880 | 1.00 | 53.84 | B | C |
| ATOM | 523 | CB | LYS | B | 175 | 28.088 | 54.629 | 90.211 | 1.00 | 56.34 | B | C |
| ATOM | 524 | CG | LYS | B | 175 | 27.275 | 54.059 | 89.040 | 1.00 | 56.05 | B | C |
| ATOM | 525 | CD | LYS | B | 175 | 27.760 | 52.665 | 88.641 | 1.00 | 57.64 | B | C |
| ATOM | 526 | CE | LYS | B | 175 | 27.867 | 51.725 | 89.851 | 1.00 | 61.46 | B | C |
| ATOM | 527 | NZ | LYS | B | 175 | 29.261 | 51.645 | 90.416 | 1.00 | 58.44 | B | N |
| ATOM | 528 | C | LYS | B | 175 | 27.977 | 57.118 | 90.209 | 1.00 | 53.12 | B | C |
| ATOM | 529 | O | LYS | B | 175 | 27.566 | 58.229 | 90.551 | 1.00 | 52.30 | B | O |
| ATOM | 530 | N | ALA | B | 176 | 28.890 | 56.934 | 89.257 | 1.00 | 52.78 | B | N |
| ATOM | 531 | CA | ALA | B | 176 | 29.498 | 58.034 | 88.508 | 1.00 | 54.00 | B | C |
| ATOM | 532 | CB | ALA | B | 176 | 29.999 | 59.119 | 89.466 | 1.00 | 52.20 | B | C |
| ATOM | 533 | C | ALA | B | 176 | 30.660 | 57.503 | 87.665 | 1.00 | 55.01 | B | C |
| ATOM | 534 | O | ALA | B | 176 | 31.396 | 58.275 | 87.047 | 1.00 | 56.45 | B | O |
| ATOM | 535 | N | ASN | B | 177 | 30.810 | 56.180 | 87.647 | 1.00 | 56.00 | B | N |
| ATOM | 536 | CA | ASN | B | 177 | 31.873 | 55.504 | 86.899 | 1.00 | 56.59 | B | C |
| ATOM | 537 | CB | ASN | B | 177 | 31.438 | 54.070 | 86.553 | 1.00 | 57.42 | B | C |
| ATOM | 538 | CG | ASN | B | 177 | 30.350 | 54.020 | 85.483 | 1.00 | 60.57 | B | C |
| ATOM | 539 | OD1 | ASN | B | 177 | 29.426 | 54.836 | 85.479 | 1.00 | 64.28 | B | O |
| ATOM | 540 | ND2 | ASN | B | 177 | 30.458 | 53.057 | 84.569 | 1.00 | 60.11 | B | N |
| ATOM | 541 | C | ASN | B | 177 | 32.321 | 56.223 | 85.622 | 1.00 | 54.67 | B | C |
| ATOM | 542 | O | ASN | B | 177 | 31.559 | 56.353 | 84.657 | 1.00 | 52.94 | B | O |
| ATOM | 543 | N | GLU | B | 178 | 33.567 | 56.687 | 85.625 | 1.00 | 52.88 | B | N |
| ATOM | 544 | CA | GLU | B | 178 | 34.124 | 57.377 | 84.468 | 1.00 | 53.25 | B | C |
| ATOM | 545 | CB | GLU | B | 178 | 34.843 | 58.655 | 84.913 | 1.00 | 55.46 | B | C |
| ATOM | 546 | CG | GLU | B | 178 | 33.908 | 59.775 | 85.359 | 1.00 | 57.37 | B | C |
| ATOM | 547 | CD | GLU | B | 178 | 33.017 | 60.299 | 84.234 | 1.00 | 60.01 | B | C |
| ATOM | 548 | OE1 | GLU | B | 178 | 32.506 | 59.485 | 83.431 | 1.00 | 58.62 | B | O |
| ATOM | 549 | OE2 | GLU | B | 178 | 32.823 | 61.533 | 84.157 | 1.00 | 61.66 | B | O |
| ATOM | 550 | C | GLU | B | 178 | 35.096 | 56.469 | 83.707 | 1.00 | 51.23 | B | C |
| ATOM | 551 | O | GLU | B | 178 | 35.979 | 56.945 | 82.989 | 1.00 | 51.86 | B | O |
| ATOM | 552 | N | SER | B | 179 | 34.920 | 55.159 | 83.863 | 1.00 | 47.67 | B | N |
| ATOM | 553 | CA | SER | B | 179 | 35.778 | 54.184 | 83.199 | 1.00 | 43.68 | B | C |
| ATOM | 554 | CB | SER | B | 179 | 35.753 | 52.859 | 83.960 | 1.00 | 40.47 | B | C |
| ATOM | 555 | OG | SER | B | 179 | 34.487 | 52.642 | 84.551 | 1.00 | 40.10 | B | O |
| ATOM | 556 | C | SER | B | 179 | 35.376 | 53.942 | 81.744 | 1.00 | 42.50 | B | C |
| ATOM | 557 | O | SER | B | 179 | 36.229 | 53.639 | 80.909 | 1.00 | 41.86 | B | O |
| ATOM | 558 | N | SER | B | 180 | 34.082 | 54.074 | 81.447 | 1.00 | 40.01 | B | N |
| ATOM | 559 | CA | SER | B | 180 | 33.576 | 53.868 | 80.091 | 1.00 | 38.05 | B | C |
| ATOM | 560 | CB | SER | B | 180 | 32.242 | 53.127 | 80.133 | 1.00 | 36.77 | B | C |
| ATOM | 561 | OG | SER | B | 180 | 32.110 | 52.405 | 81.341 | 1.00 | 38.89 | B | O |
| ATOM | 562 | C | SER | B | 180 | 33.399 | 55.197 | 79.371 | 1.00 | 37.66 | B | C |
| ATOM | 563 | O | SER | B | 180 | 32.653 | 55.306 | 78.400 | 1.00 | 38.36 | B | O |
| ATOM | 564 | N | TYR | B | 181 | 34.095 | 56.208 | 79.863 | 1.00 | 36.95 | B | N |
| ATOM | 565 | CA | TYR | B | 181 | 34.036 | 57.539 | 79.293 | 1.00 | 38.05 | B | C |
| ATOM | 566 | CB | TYR | B | 181 | 34.512 | 58.556 | 80.335 | 1.00 | 43.62 | B | C |
| ATOM | 567 | CG | TYR | B | 181 | 33.618 | 59.762 | 80.514 | 1.00 | 49.10 | B | C |
| ATOM | 568 | CD1 | TYR | B | 181 | 34.157 | 61.051 | 80.541 | 1.00 | 52.53 | B | C |
| ATOM | 569 | CE1 | TYR | B | 181 | 33.344 | 62.175 | 80.738 | 1.00 | 56.87 | B | C |
| ATOM | 570 | CD2 | TYR | B | 181 | 32.240 | 59.617 | 80.685 | 1.00 | 53.06 | B | C |
| ATOM | 571 | CE2 | TYR | B | 181 | 31.412 | 60.733 | 80.883 | 1.00 | 57.51 | B | C |
| ATOM | 572 | CZ | TYR | B | 181 | 31.970 | 62.010 | 80.911 | 1.00 | 58.94 | B | C |
| ATOM | 573 | OH | TYR | B | 181 | 31.158 | 63.113 | 81.118 | 1.00 | 58.06 | B | O |
| ATOM | 574 | C | TYR | B | 181 | 34.945 | 57.595 | 78.069 | 1.00 | 34.85 | B | C |
| ATOM | 575 | O | TYR | B | 181 | 36.058 | 57.074 | 78.093 | 1.00 | 34.33 | B | O |
| ATOM | 576 | N | PRO | B | 182 | 34.478 | 58.216 | 76.975 | 1.00 | 33.72 | B | N |
| ATOM | 577 | CD | PRO | B | 182 | 33.165 | 58.845 | 76.757 | 1.00 | 31.35 | B | C |
| ATOM | 578 | CA | PRO | B | 182 | 35.332 | 58.293 | 75.785 | 1.00 | 32.21 | B | C |
| ATOM | 579 | CB | PRO | B | 182 | 34.500 | 59.103 | 74.788 | 1.00 | 30.38 | B | C |
| ATOM | 580 | CG | PRO | B | 182 | 33.416 | 59.736 | 75.592 | 1.00 | 29.41 | B | C |
| ATOM | 581 | C | PRO | B | 182 | 36.656 | 58.979 | 76.117 | 1.00 | 32.80 | B | C |
| ATOM | 582 | O | PRO | B | 182 | 36.753 | 59.683 | 77.126 | 1.00 | 36.04 | B | O |
| ATOM | 583 | N | VAL | B | 183 | 37.671 | 58.760 | 75.283 | 1.00 | 30.66 | B | N |
| ATOM | 584 | CA | VAL | B | 183 | 38.982 | 59.375 | 75.480 | 1.00 | 28.79 | B | C |
| ATOM | 585 | CB | VAL | B | 183 | 40.094 | 58.312 | 75.640 | 1.00 | 27.90 | B | C |
| ATOM | 586 | CG1 | VAL | B | 183 | 41.392 | 58.973 | 76.057 | 1.00 | 24.75 | B | C |
| ATOM | 587 | CG2 | VAL | B | 183 | 39.683 | 57.280 | 76.666 | 1.00 | 28.04 | B | C |
| ATOM | 588 | C | VAL | B | 183 | 39.325 | 60.259 | 74.282 | 1.00 | 29.11 | B | C |
| ATOM | 589 | O | VAL | B | 183 | 39.727 | 59.766 | 73.230 | 1.00 | 27.69 | B | O |
| ATOM | 590 | N | PHE | B | 184 | 39.147 | 61.565 | 74.447 | 1.00 | 29.86 | B | N |
| ATOM | 591 | CA | PHE | B | 184 | 39.438 | 62.527 | 73.393 | 1.00 | 32.47 | B | C |
| ATOM | 592 | CB | PHE | B | 184 | 38.578 | 63.777 | 73.568 | 1.00 | 37.52 | B | C |
| ATOM | 593 | CG | PHE | B | 184 | 37.127 | 63.568 | 73.251 | 1.00 | 43.27 | B | C |
| ATOM | 594 | CD1 | PHE | B | 184 | 36.538 | 64.228 | 72.172 | 1.00 | 47.81 | B | C |
| ATOM | 595 | CD2 | PHE | B | 184 | 36.344 | 62.721 | 74.030 | 1.00 | 43.95 | B | C |
| ATOM | 596 | CE1 | PHE | B | 184 | 35.182 | 64.044 | 71.874 | 1.00 | 50.93 | B | C |
| ATOM | 597 | CE2 | PHE | B | 184 | 34.990 | 62.528 | 73.744 | 1.00 | 45.52 | B | C |
| ATOM | 598 | CZ | PHE | B | 184 | 34.408 | 63.190 | 72.666 | 1.00 | 48.21 | B | C |
| ATOM | 599 | C | PHE | B | 184 | 40.901 | 62.919 | 73.494 | 1.00 | 31.89 | B | C |
| ATOM | 600 | O | PHE | B | 184 | 41.382 | 63.210 | 74.581 | 1.00 | 33.69 | B | O |
| ATOM | 601 | N | THR | B | 185 | 41.622 | 62.934 | 72.379 | 1.00 | 30.48 | B | N |
| ATOM | 602 | CA | THR | B | 185 | 43.024 | 63.309 | 72.457 | 1.00 | 30.58 | B | C |
| ATOM | 603 | CB | THR | B | 185 | 43.742 | 63.152 | 71.085 | 1.00 | 26.62 | B | C |
| ATOM | 604 | OG1 | THR | B | 185 | 44.424 | 64.363 | 70.743 | 1.00 | 25.44 | B | O |
| ATOM | 605 | CG2 | THR | B | 185 | 42.755 | 62.788 | 70.011 | 1.00 | 26.27 | B | C |
| ATOM | 606 | C | THR | B | 185 | 43.102 | 64.748 | 72.979 | 1.00 | 31.26 | B | C |
| ATOM | 607 | O | THR | B | 185 | 42.338 | 65.619 | 72.556 | 1.00 | 31.45 | B | O |
| ATOM | 608 | N | PRO | B | 186 | 44.013 | 65.003 | 73.933 | 1.00 | 32.64 | B | N |
| ATOM | 609 | CD | PRO | B | 186 | 44.944 | 64.011 | 74.498 | 1.00 | 31.64 | B | C |
| ATOM | 610 | CA | PRO | B | 186 | 44.202 | 66.327 | 74.540 | 1.00 | 33.09 | B | C |
| ATOM | 611 | CB | PRO | B | 186 | 45.316 | 66.103 | 75.564 | 1.00 | 31.76 | B | C |
| ATOM | 612 | CG | PRO | B | 186 | 46.019 | 64.868 | 75.092 | 1.00 | 34.42 | B | C |
| ATOM | 613 | C | PRO | B | 186 | 44.544 | 67.456 | 73.584 | 1.00 | 34.02 | B | C |
| ATOM | 614 | O | PRO | B | 186 | 45.075 | 67.232 | 72.494 | 1.00 | 34.33 | B | O |
| ATOM | 615 | N | ALA | B | 187 | 44.231 | 68.676 | 74.007 | 1.00 | 33.62 | B | N |
| ATOM | 616 | CA | ALA | B | 187 | 44.527 | 69.853 | 73.210 | 1.00 | 35.45 | B | C |
| ATOM | 617 | CB | ALA | B | 187 | 43.842 | 71.077 | 73.808 | 1.00 | 30.34 | B | C |
| ATOM | 618 | C | ALA | B | 187 | 46.042 | 70.036 | 73.232 | 1.00 | 37.58 | B | C |
| ATOM | 619 | O | ALA | B | 187 | 46.677 | 69.848 | 74.269 | 1.00 | 39.06 | B | O |
| ATOM | 620 | N | LEU | B | 188 | 46.632 | 70.378 | 72.093 | 1.00 | 39.56 | B | N |
| ATOM | 621 | CA | LEU | B | 188 | 48.068 | 70.585 | 72.068 | 1.00 | 42.38 | B | C |
| ATOM | 622 | CB | LEU | B | 188 | 48.625 | 70.479 | 70.642 | 1.00 | 43.21 | B | C |
| ATOM | 623 | CG | LEU | B | 188 | 47.755 | 70.893 | 69.461 | 1.00 | 45.64 | B | C |
| ATOM | 624 | CD1 | LEU | B | 188 | 48.395 | 72.087 | 68.754 | 1.00 | 43.50 | B | C |
| ATOM | 625 | CD2 | LEU | B | 188 | 47.602 | 69.707 | 68.501 | 1.00 | 46.62 | B | C |
| ATOM | 626 | C | LEU | B | 188 | 48.328 | 71.970 | 72.635 | 1.00 | 44.09 | B | C |
| ATOM | 627 | O | LEU | B | 188 | 47.511 | 72.877 | 72.462 | 1.00 | 42.70 | B | O |
| ATOM | 628 | N | LYS | B | 189 | 49.453 | 72.123 | 73.329 | 1.00 | 46.29 | B | N |
| ATOM | 629 | CA | LYS | B | 189 | 49.822 | 73.400 | 73.929 | 1.00 | 50.12 | B | C |
| ATOM | 630 | CB | LYS | B | 189 | 51.119 | 73.252 | 74.715 | 1.00 | 47.89 | B | C |
| ATOM | 631 | CG | LYS | B | 189 | 51.168 | 71.996 | 75.563 | 1.00 | 48.12 | B | C |
| ATOM | 632 | CD | LYS | B | 189 | 50.695 | 72.275 | 76.978 | 1.00 | 52.14 | B | C |
| ATOM | 633 | CE | LYS | B | 189 | 49.436 | 71.486 | 77.314 | 1.00 | 53.90 | B | C |
| ATOM | 634 | NZ | LYS | B | 189 | 49.719 | 70.031 | 77.490 | 1.00 | 53.78 | B | N |
| ATOM | 635 | C | LYS | B | 189 | 49.993 | 74.482 | 72.871 | 1.00 | 54.45 | B | C |
| ATOM | 636 | O | LYS | B | 189 | 50.114 | 74.187 | 71.677 | 1.00 | 56.30 | B | O |
| ATOM | 637 | N | LYS | B | 190 | 49.987 | 75.737 | 73.308 | 1.00 | 58.12 | B | N |
| ATOM | 638 | CA | LYS | B | 190 | 50.151 | 76.854 | 72.384 | 1.00 | 62.62 | B | C |
| ATOM | 639 | CB | LYS | B | 190 | 50.260 | 78.177 | 73.156 | 1.00 | 63.04 | B | C |
| ATOM | 640 | CG | LYS | B | 190 | 50.043 | 79.433 | 72.309 | 1.00 | 63.49 | B | C |
| ATOM | 641 | CD | LYS | B | 190 | 51.070 | 80.519 | 72.636 | 1.00 | 64.82 | B | C |
| ATOM | 642 | CE | LYS | B | 190 | 51.130 | 80.826 | 74.136 | 1.00 | 65.85 | B | C |
| ATOM | 643 | NZ | LYS | B | 190 | 52.525 | 80.774 | 74.681 | 1.00 | 64.65 | B | N |
| ATOM | 644 | C | LYS | B | 190 | 51.438 | 76.598 | 71.607 | 1.00 | 62.23 | B | C |
| ATOM | 645 | O | LYS | B | 190 | 52.493 | 76.361 | 72.208 | 1.00 | 61.80 | B | O |
| ATOM | 646 | N | GLY | B | 191 | 51.352 | 76.629 | 70.280 | 1.00 | 61.60 | B | N |
| ATOM | 647 | CA | GLY | B | 191 | 52.536 | 76.388 | 69.476 | 1.00 | 61.20 | B | C |
| ATOM | 648 | C | GLY | B | 191 | 53.246 | 75.096 | 69.859 | 1.00 | 59.53 | B | C |
| ATOM | 649 | O | GLY | B | 191 | 54.195 | 75.087 | 70.655 | 1.00 | 57.62 | B | O |
| ATOM | 650 | N | GLU | B | 192 | 52.768 | 73.993 | 69.295 | 1.00 | 57.00 | B | N |
| ATOM | 651 | CA | GLU | B | 192 | 53.343 | 72.679 | 69.546 | 1.00 | 51.89 | B | C |
| ATOM | 652 | CB | GLU | B | 192 | 52.576 | 71.953 | 70.658 | 1.00 | 50.04 | B | C |
| ATOM | 653 | CG | GLU | B | 192 | 53.162 | 70.599 | 71.040 | 1.00 | 47.63 | B | C |
| ATOM | 654 | CD | GLU | B | 192 | 52.206 | 69.759 | 71.878 | 1.00 | 49.74 | B | C |
| ATOM | 655 | OE1 | GLU | B | 192 | 52.548 | 68.602 | 72.215 | 1.00 | 47.12 | B | O |
| ATOM | 656 | OE2 | GLU | B | 192 | 51.107 | 70.256 | 72.202 | 1.00 | 50.91 | B | O |
| ATOM | 657 | C | GLU | B | 192 | 53.217 | 71.915 | 68.240 | 1.00 | 49.53 | B | C |
| ATOM | 658 | O | GLU | B | 192 | 52.325 | 72.200 | 67.432 | 1.00 | 52.23 | B | O |
| ATOM | 659 | N | ASP | B | 193 | 54.111 | 70.957 | 68.022 | 1.00 | 43.41 | B | N |
| ATOM | 660 | CA | ASP | B | 193 | 54.071 | 70.177 | 66.798 | 1.00 | 39.71 | B | C |
| ATOM | 661 | CB | ASP | B | 193 | 55.368 | 69.385 | 66.631 | 1.00 | 39.11 | B | C |
| ATOM | 662 | CG | ASP | B | 193 | 55.550 | 68.850 | 65.224 | 1.00 | 40.69 | B | C |
| ATOM | 663 | OD1 | ASP | B | 193 | 55.989 | 67.690 | 65.092 | 1.00 | 41.96 | B | O |
| ATOM | 664 | OD2 | ASP | B | 193 | 55.257 | 69.582 | 64.252 | 1.00 | 41.13 | B | O |
| ATOM | 665 | C | ASP | B | 193 | 52.877 | 69.235 | 66.841 | 1.00 | 35.11 | B | C |
| ATOM | 666 | O | ASP | B | 193 | 52.803 | 68.347 | 67.689 | 1.00 | 33.18 | B | O |
| ATOM | 667 | N | PRO | B | 194 | 51.912 | 69.429 | 65.931 | 1.00 | 32.34 | B | N |
| ATOM | 668 | CD | PRO | B | 194 | 51.857 | 70.451 | 64.876 | 1.00 | 30.41 | B | C |
| ATOM | 669 | CA | PRO | B | 194 | 50.735 | 68.558 | 65.915 | 1.00 | 29.68 | B | C |
| ATOM | 670 | CB | PRO | B | 194 | 49.754 | 69.282 | 64.993 | 1.00 | 27.53 | B | C |
| ATOM | 671 | CG | PRO | B | 194 | 50.398 | 70.601 | 64.648 | 1.00 | 29.58 | B | C |
| ATOM | 672 | C | PRO | B | 194 | 51.084 | 67.171 | 65.390 | 1.00 | 30.52 | B | C |
| ATOM | 673 | O | PRO | B | 194 | 50.297 | 66.233 | 65.517 | 1.00 | 30.22 | B | O |
| ATOM | 674 | N | PHE | B | 195 | 52.274 | 67.039 | 64.816 | 1.00 | 30.39 | B | N |
| ATOM | 675 | CA | PHE | B | 195 | 52.691 | 65.768 | 64.247 | 1.00 | 32.56 | B | C |
| ATOM | 676 | CB | PHE | B | 195 | 53.036 | 65.974 | 62.768 | 1.00 | 28.39 | B | C |
| ATOM | 677 | CG | PHE | B | 195 | 51.968 | 66.704 | 62.007 | 1.00 | 25.44 | B | C |
| ATOM | 678 | CD1 | PHE | B | 195 | 50.766 | 66.074 | 61.693 | 1.00 | 25.38 | B | C |
| ATOM | 679 | CD2 | PHE | B | 195 | 52.135 | 68.033 | 61.654 | 1.00 | 23.11 | B | C |
| ATOM | 680 | CE1 | PHE | B | 195 | 49.746 | 66.762 | 61.040 | 1.00 | 22.46 | B | C |
| ATOM | 681 | CE2 | PHE | B | 195 | 51.120 | 68.725 | 61.001 | 1.00 | 24.66 | B | C |
| ATOM | 682 | CZ | PHE | B | 195 | 49.923 | 68.086 | 60.695 | 1.00 | 22.12 | B | C |
| ATOM | 683 | C | PHE | B | 195 | 53.844 | 65.082 | 64.971 | 1.00 | 35.01 | B | C |
| ATOM | 684 | O | PHE | B | 195 | 54.585 | 64.308 | 64.362 | 1.00 | 35.18 | B | O |
| ATOM | 685 | N | ARG | B | 196 | 53.979 | 65.354 | 66.269 | 1.00 | 36.86 | B | N |
| ATOM | 686 | CA | ARG | B | 196 | 55.034 | 64.756 | 67.090 | 1.00 | 36.39 | B | C |
| ATOM | 687 | CB | ARG | B | 196 | 54.897 | 65.203 | 68.545 | 1.00 | 38.83 | B | C |
| ATOM | 688 | CG | ARG | B | 196 | 54.858 | 66.706 | 68.722 | 1.00 | 46.34 | B | C |
| ATOM | 689 | CD | ARG | B | 196 | 54.926 | 67.083 | 70.188 | 1.00 | 51.02 | B | C |
| ATOM | 690 | NE | ARG | B | 196 | 55.909 | 66.278 | 70.905 | 1.00 | 55.08 | B | N |
| ATOM | 691 | CZ | ARG | B | 196 | 56.373 | 66.572 | 72.113 | 1.00 | 56.75 | B | C |
| ATOM | 692 | NH1 | ARG | B | 196 | 55.942 | 67.656 | 72.745 | 1.00 | 56.09 | B | N |
| ATOM | 693 | NH2 | ARG | B | 196 | 57.272 | 65.786 | 72.688 | 1.00 | 58.20 | B | N |
| ATOM | 694 | C | ARG | B | 196 | 54.986 | 63.236 | 67.036 | 1.00 | 35.46 | B | C |
| ATOM | 695 | O | ARG | B | 196 | 53.923 | 62.632 | 67.139 | 1.00 | 34.77 | B | O |
| ATOM | 696 | N | THR | B | 197 | 56.149 | 62.617 | 66.900 | 1.00 | 37.43 | B | N |
| ATOM | 697 | CA | THR | B | 197 | 56.217 | 61.168 | 66.821 | 1.00 | 39.96 | B | C |
| ATOM | 698 | CB | THR | B | 197 | 56.756 | 60.742 | 65.439 | 1.00 | 39.34 | B | C |
| ATOM | 699 | OG1 | THR | B | 197 | 56.479 | 59.355 | 65.224 | 1.00 | 40.72 | B | O |
| ATOM | 700 | CG2 | THR | B | 197 | 58.259 | 60.986 | 65.349 | 1.00 | 38.40 | B | C |
| ATOM | 701 | C | THR | B | 197 | 57.088 | 60.545 | 67.915 | 1.00 | 42.00 | B | C |
| ATOM | 702 | O | THR | B | 197 | 57.401 | 59.351 | 67.863 | 1.00 | 42.26 | B | O |
| ATOM | 703 | N | ASP | B | 198 | 57.455 | 61.348 | 68.913 | 1.00 | 41.97 | B | N |
| ATOM | 704 | CA | ASP | B | 198 | 58.318 | 60.889 | 70.000 | 1.00 | 42.14 | B | C |
| ATOM | 705 | CB | ASP | B | 198 | 59.305 | 61.992 | 70.368 | 1.00 | 41.50 | B | C |
| ATOM | 706 | CG | ASP | B | 198 | 58.614 | 63.269 | 70.791 | 1.00 | 42.96 | B | C |
| ATOM | 707 | OD1 | ASP | B | 198 | 57.936 | 63.886 | 69.947 | 1.00 | 46.43 | B | O |
| ATOM | 708 | OD2 | ASP | B | 198 | 58.747 | 63.660 | 71.969 | 1.00 | 45.23 | B | O |
| ATOM | 709 | C | ASP | B | 198 | 57.609 | 60.432 | 71.270 | 1.00 | 43.50 | B | C |
| ATOM | 710 | O | ASP | B | 198 | 58.259 | 59.994 | 72.221 | 1.00 | 44.17 | B | O |
| ATOM | 711 | N | ASN | B | 199 | 56.286 | 60.528 | 71.295 | 1.00 | 43.03 | B | N |
| ATOM | 712 | CA | ASN | B | 199 | 55.532 | 60.132 | 72.478 | 1.00 | 42.66 | B | C |
| ATOM | 713 | CB | ASN | B | 199 | 54.705 | 61.319 | 72.975 | 1.00 | 45.42 | B | C |
| ATOM | 714 | CG | ASN | B | 199 | 54.202 | 62.196 | 71.834 | 1.00 | 51.21 | B | C |
| ATOM | 715 | OD1 | ASN | B | 199 | 54.076 | 63.417 | 71.983 | 1.00 | 54.57 | B | O |
| ATOM | 716 | ND2 | ASN | B | 199 | 53.915 | 61.576 | 70.685 | 1.00 | 49.30 | B | N |
| ATOM | 717 | C | ASN | B | 199 | 54.615 | 58.938 | 72.211 | 1.00 | 40.28 | B | C |
| ATOM | 718 | O | ASN | B | 199 | 53.617 | 58.743 | 72.909 | 1.00 | 39.69 | B | O |
| ATOM | 719 | N | LEU | B | 200 | 54.962 | 58.136 | 71.208 | 1.00 | 35.98 | B | N |
| ATOM | 720 | CA | LEU | B | 200 | 54.159 | 56.972 | 70.854 | 1.00 | 31.08 | B | C |
| ATOM | 721 | CB | LEU | B | 200 | 54.350 | 56.622 | 69.381 | 1.00 | 31.57 | B | C |
| ATOM | 722 | CG | LEU | B | 200 | 53.899 | 57.606 | 68.303 | 1.00 | 33.19 | B | C |
| ATOM | 723 | CD1 | LEU | B | 200 | 54.519 | 57.208 | 66.979 | 1.00 | 31.54 | B | C |
| ATOM | 724 | CD2 | LEU | B | 200 | 52.384 | 57.601 | 68.191 | 1.00 | 32.35 | B | C |
| ATOM | 725 | C | LEU | B | 200 | 54.509 | 55.748 | 71.685 | 1.00 | 29.68 | B | C |
| ATOM | 726 | O | LEU | B | 200 | 55.668 | 55.534 | 72.038 | 1.00 | 30.91 | B | O |
| ATOM | 727 | N | PRO | B | 201 | 53.502 | 54.927 | 72.012 | 1.00 | 27.74 | B | N |
| ATOM | 728 | CD | PRO | B | 201 | 52.084 | 55.127 | 71.677 | 1.00 | 26.97 | B | C |
| ATOM | 729 | CA | PRO | B | 201 | 53.704 | 53.709 | 72.802 | 1.00 | 30.06 | B | C |
| ATOM | 730 | CB | PRO | B | 201 | 52.295 | 53.124 | 72.929 | 1.00 | 25.93 | B | C |
| ATOM | 731 | CG | PRO | B | 201 | 51.384 | 54.269 | 72.675 | 1.00 | 24.79 | B | C |
| ATOM | 732 | C | PRO | B | 201 | 54.667 | 52.745 | 72.109 | 1.00 | 32.43 | B | C |
| ATOM | 733 | O | PRO | B | 201 | 55.128 | 53.009 | 71.005 | 1.00 | 35.17 | B | O |
| ATOM | 734 | N | GLU | B | 202 | 54.968 | 51.628 | 72.759 | 1.00 | 34.26 | B | N |
| ATOM | 735 | CA | GLU | B | 202 | 55.873 | 50.641 | 72.192 | 1.00 | 36.24 | B | C |
| ATOM | 736 | CB | GLU | B | 202 | 56.701 | 49.994 | 73.307 | 1.00 | 42.86 | B | C |
| ATOM | 737 | CG | GLU | B | 202 | 57.174 | 50.974 | 74.381 | 1.00 | 52.45 | B | C |
| ATOM | 738 | CD | GLU | B | 202 | 57.716 | 50.277 | 75.631 | 1.00 | 58.63 | B | C |
| ATOM | 739 | OE1 | GLU | B | 202 | 57.319 | 49.116 | 75.897 | 1.00 | 59.94 | B | O |
| ATOM | 740 | OE2 | GLU | B | 202 | 58.540 | 50.895 | 76.349 | 1.00 | 60.92 | B | O |
| ATOM | 741 | C | GLU | B | 202 | 55.068 | 49.577 | 71.456 | 1.00 | 34.18 | B | C |
| ATOM | 742 | O | GLU | B | 202 | 53.876 | 49.415 | 71.705 | 1.00 | 32.24 | B | O |
| ATOM | 743 | N | ASN | B | 203 | 55.714 | 48.856 | 70.546 | 1.00 | 33.29 | B | N |
| ATOM | 744 | CA | ASN | B | 203 | 55.025 | 47.811 | 69.794 | 1.00 | 32.06 | B | C |
| ATOM | 745 | CB | ASN | B | 203 | 55.896 | 47.315 | 68.640 | 1.00 | 31.14 | B | C |
| ATOM | 746 | CG | ASN | B | 203 | 56.144 | 48.383 | 67.592 | 1.00 | 30.83 | B | C |
| ATOM | 747 | OD1 | ASN | B | 203 | 56.845 | 48.149 | 66.613 | 1.00 | 33.77 | B | O |
| ATOM | 748 | ND2 | ASN | B | 203 | 55.574 | 49.560 | 67.794 | 1.00 | 28.72 | B | N |
| ATOM | 749 | C | ASN | B | 203 | 54.695 | 46.650 | 70.717 | 1.00 | 32.68 | B | C |
| ATOM | 750 | O | ASN | B | 203 | 55.417 | 46.389 | 71.679 | 1.00 | 34.21 | B | O |
| ATOM | 751 | N | LEU | B | 204 | 53.607 | 45.949 | 70.421 | 1.00 | 32.69 | B | N |
| ATOM | 752 | CA | LEU | B | 204 | 53.182 | 44.821 | 71.242 | 1.00 | 34.29 | B | C |
| ATOM | 753 | CB | LEU | B | 204 | 51.777 | 45.080 | 71.793 | 1.00 | 34.66 | B | C |
| ATOM | 754 | CG | LEU | B | 204 | 51.702 | 46.197 | 72.836 | 1.00 | 35.60 | B | C |
| ATOM | 755 | CD1 | LEU | B | 204 | 50.251 | 46.509 | 73.143 | 1.00 | 37.14 | B | C |
| ATOM | 756 | CD2 | LEU | B | 204 | 52.443 | 45.773 | 74.096 | 1.00 | 31.38 | B | C |
| ATOM | 757 | C | LEU | B | 204 | 53.207 | 43.497 | 70.490 | 1.00 | 33.23 | B | C |
| ATOM | 758 | O | LEU | B | 204 | 53.043 | 42.434 | 71.081 | 1.00 | 34.41 | B | O |
| ATOM | 759 | N | GLY | B | 205 | 53.403 | 43.572 | 69.181 | 1.00 | 33.31 | B | N |
| ATOM | 760 | CA | GLY | B | 205 | 53.466 | 42.375 | 68.367 | 1.00 | 30.99 | B | C |
| ATOM | 761 | C | GLY | B | 205 | 52.386 | 41.322 | 68.545 | 1.00 | 30.90 | B | C |
| ATOM | 762 | O | GLY | B | 205 | 52.663 | 40.133 | 68.386 | 1.00 | 31.54 | B | O |
| ATOM | 763 | N | TYR | B | 206 | 51.164 | 41.724 | 68.878 | 1.00 | 30.46 | B | N |
| ATOM | 764 | CA | TYR | B | 206 | 50.091 | 40.741 | 69.019 | 1.00 | 31.94 | B | C |
| ATOM | 765 | CB | TYR | B | 206 | 48.852 | 41.350 | 69.687 | 1.00 | 35.00 | B | C |
| ATOM | 766 | CG | TYR | B | 206 | 49.020 | 41.743 | 71.141 | 1.00 | 38.27 | B | C |
| ATOM | 767 | CD1 | TYR | B | 206 | 49.889 | 41.050 | 71.985 | 1.00 | 38.63 | B | C |
| ATOM | 768 | CE1 | TYR | B | 206 | 50.030 | 41.410 | 73.322 | 1.00 | 40.43 | B | C |
| ATOM | 769 | CD2 | TYR | B | 206 | 48.297 | 42.808 | 71.674 | 1.00 | 38.80 | B | C |
| ATOM | 770 | CE2 | TYR | B | 206 | 48.429 | 43.174 | 73.005 | 1.00 | 40.35 | B | C |
| ATOM | 771 | CZ | TYR | B | 206 | 49.296 | 42.474 | 73.823 | 1.00 | 41.09 | B | C |
| ATOM | 772 | OH | TYR | B | 206 | 49.425 | 42.847 | 75.141 | 1.00 | 44.00 | B | O |
| ATOM | 773 | C | TYR | B | 206 | 49.719 | 40.305 | 67.608 | 1.00 | 31.03 | B | C |
| ATOM | 774 | O | TYR | B | 206 | 50.118 | 40.938 | 66.634 | 1.00 | 30.35 | B | O |
| ATOM | 775 | N | HIS | B | 207 | 48.950 | 39.233 | 67.494 | 1.00 | 30.08 | B | N |
| ATOM | 776 | CA | HIS | B | 207 | 48.537 | 38.748 | 66.188 | 1.00 | 30.75 | B | C |
| ATOM | 777 | CB | HIS | B | 207 | 48.739 | 37.232 | 66.099 | 1.00 | 34.36 | B | C |
| ATOM | 778 | CG | HIS | B | 207 | 48.428 | 36.662 | 64.750 | 1.00 | 37.80 | B | C |
| ATOM | 779 | CD2 | HIS | B | 207 | 49.146 | 36.645 | 63.601 | 1.00 | 36.90 | B | C |
| ATOM | 780 | ND1 | HIS | B | 207 | 47.233 | 36.035 | 64.464 | 1.00 | 40.38 | B | N |
| ATOM | 781 | CE1 | HIS | B | 207 | 47.229 | 35.656 | 63.198 | 1.00 | 39.58 | B | C |
| ATOM | 782 | NE2 | HIS | B | 207 | 48.377 | 36.014 | 62.653 | 1.00 | 37.79 | B | N |
| ATOM | 783 | C | HIS | B | 207 | 47.070 | 39.098 | 65.942 | 1.00 | 31.09 | B | C |
| ATOM | 784 | O | HIS | B | 207 | 46.187 | 38.679 | 66.696 | 1.00 | 29.16 | B | O |
| ATOM | 785 | N | LEU | B | 208 | 46.817 | 39.873 | 64.888 | 1.00 | 31.02 | B | N |
| ATOM | 786 | CA | LEU | B | 208 | 45.459 | 40.280 | 64.540 | 1.00 | 27.74 | B | C |
| ATOM | 787 | CB | LEU | B | 208 | 45.463 | 41.704 | 64.009 | 1.00 | 25.80 | B | C |
| ATOM | 788 | CG | LEU | B | 208 | 46.021 | 42.746 | 64.973 | 1.00 | 23.68 | B | C |
| ATOM | 789 | CD1 | LEU | B | 208 | 46.263 | 44.030 | 64.212 | 1.00 | 26.30 | B | C |
| ATOM | 790 | CD2 | LEU | B | 208 | 45.059 | 42.973 | 66.123 | 1.00 | 20.07 | B | C |
| ATOM | 791 | C | LEU | B | 208 | 44.849 | 39.355 | 63.500 | 1.00 | 27.18 | B | C |
| ATOM | 792 | O | LEU | B | 208 | 45.529 | 38.895 | 62.592 | 1.00 | 28.20 | B | O |
| ATOM | 793 | N | LYS | B | 209 | 43.558 | 39.087 | 63.632 | 1.00 | 28.47 | B | N |
| ATOM | 794 | CA | LYS | B | 209 | 42.878 | 38.205 | 62.699 | 1.00 | 28.55 | B | C |
| ATOM | 795 | CB | LYS | B | 209 | 43.143 | 36.749 | 63.080 | 1.00 | 30.87 | B | C |
| ATOM | 796 | CG | LYS | B | 209 | 42.633 | 35.732 | 62.075 | 1.00 | 33.93 | B | C |
| ATOM | 797 | CD | LYS | B | 209 | 42.744 | 34.309 | 62.626 | 1.00 | 37.92 | B | C |
| ATOM | 798 | CE | LYS | B | 209 | 42.380 | 33.264 | 61.567 | 1.00 | 38.06 | B | C |
| ATOM | 799 | NZ | LYS | B | 209 | 41.978 | 31.962 | 62.170 | 1.00 | 36.03 | B | N |
| ATOM | 800 | C | LYS | B | 209 | 41.375 | 38.462 | 62.673 | 1.00 | 29.99 | B | C |
| ATOM | 801 | O | LYS | B | 209 | 40.730 | 38.578 | 63.715 | 1.00 | 29.75 | B | O |
| ATOM | 802 | N | MET | B | 210 | 40.827 | 38.550 | 61.467 | 1.00 | 28.56 | B | N |
| ATOM | 803 | CA | MET | B | 210 | 39.404 | 38.779 | 61.283 | 1.00 | 27.78 | B | C |
| ATOM | 804 | CB | MET | B | 210 | 39.114 | 39.079 | 59.813 | 1.00 | 27.25 | B | C |
| ATOM | 805 | CG | MET | B | 210 | 37.826 | 39.840 | 59.577 | 1.00 | 30.28 | B | C |
| ATOM | 806 | SD | MET | B | 210 | 38.039 | 41.634 | 59.550 | 1.00 | 30.95 | B | S |
| ATOM | 807 | CE | MET | B | 210 | 39.750 | 41.787 | 59.846 | 1.00 | 20.95 | B | C |
| ATOM | 808 | C | MET | B | 210 | 38.642 | 37.536 | 61.703 | 1.00 | 27.37 | B | C |
| ATOM | 809 | O | MET | B | 210 | 39.110 | 36.423 | 61.498 | 1.00 | 30.49 | B | O |
| ATOM | 810 | N | LYS | B | 211 | 37.473 | 37.728 | 62.298 | 1.00 | 26.09 | B | N |
| ATOM | 811 | CA | LYS | B | 211 | 36.642 | 36.611 | 62.722 | 1.00 | 26.48 | B | C |
| ATOM | 812 | CB | LYS | B | 211 | 36.961 | 36.210 | 64.159 | 1.00 | 30.10 | B | C |
| ATOM | 813 | CG | LYS | B | 211 | 36.407 | 34.849 | 64.540 | 1.00 | 31.69 | B | C |
| ATOM | 814 | CD | LYS | B | 211 | 35.628 | 34.929 | 65.831 | 1.00 | 36.27 | B | C |
| ATOM | 815 | CE | LYS | B | 211 | 36.269 | 34.073 | 66.901 | 1.00 | 40.19 | B | C |
| ATOM | 816 | NZ | LYS | B | 211 | 35.789 | 32.667 | 66.807 | 1.00 | 45.15 | B | N |
| ATOM | 817 | C | LYS | B | 211 | 35.173 | 36.999 | 62.615 | 1.00 | 27.76 | B | C |
| ATOM | 818 | O | LYS | B | 211 | 34.664 | 37.789 | 63.408 | 1.00 | 29.39 | B | O |
| ATOM | 819 | N | ASP | B | 212 | 34.498 | 36.442 | 61.617 | 1.00 | 28.12 | B | N |
| ATOM | 820 | CA | ASP | B | 212 | 33.092 | 36.723 | 61.380 | 1.00 | 27.65 | B | C |
| ATOM | 821 | CB | ASP | B | 212 | 32.240 | 36.122 | 62.499 | 1.00 | 30.38 | B | C |
| ATOM | 822 | CG | ASP | B | 212 | 32.217 | 34.603 | 62.461 | 1.00 | 33.35 | B | C |
| ATOM | 823 | OD1 | ASP | B | 212 | 32.371 | 34.027 | 61.359 | 1.00 | 35.06 | B | O |
| ATOM | 824 | OD2 | ASP | B | 212 | 32.047 | 33.982 | 63.531 | 1.00 | 33.87 | B | O |
| ATOM | 825 | C | ASP | B | 212 | 32.795 | 38.213 | 61.238 | 1.00 | 25.02 | B | C |
| ATOM | 826 | O | ASP | B | 212 | 31.776 | 38.697 | 61.724 | 1.00 | 26.52 | B | O |
| ATOM | 827 | N | GLY | B | 213 | 33.688 | 38.933 | 60.570 | 1.00 | 23.64 | B | N |
| ATOM | 828 | CA | GLY | B | 213 | 33.485 | 40.354 | 60.352 | 1.00 | 21.83 | B | C |
| ATOM | 829 | C | GLY | B | 213 | 34.105 | 41.289 | 61.369 | 1.00 | 22.60 | B | C |
| ATOM | 830 | O | GLY | B | 213 | 34.003 | 42.510 | 61.225 | 1.00 | 20.96 | B | O |
| ATOM | 831 | N | VAL | B | 214 | 34.755 | 40.736 | 62.389 | 1.00 | 21.02 | B | N |
| ATOM | 832 | CA | VAL | B | 214 | 35.360 | 41.565 | 63.422 | 1.00 | 21.30 | B | C |
| ATOM | 833 | CB | VAL | B | 214 | 34.598 | 41.398 | 64.780 | 1.00 | 21.60 | B | C |
| ATOM | 834 | CG1 | VAL | B | 214 | 35.240 | 42.273 | 65.863 | 1.00 | 18.68 | B | C |
| ATOM | 835 | CG2 | VAL | B | 214 | 33.121 | 41.779 | 64.606 | 1.00 | 18.47 | B | C |
| ATOM | 836 | C | VAL | B | 214 | 36.839 | 41.248 | 63.630 | 1.00 | 22.64 | B | C |
| ATOM | 837 | O | VAL | B | 214 | 37.246 | 40.089 | 63.565 | 1.00 | 21.35 | B | O |
| ATOM | 838 | N | VAL | B | 215 | 37.642 | 42.283 | 63.873 | 1.00 | 22.29 | B | N |
| ATOM | 839 | CA | VAL | B | 215 | 39.068 | 42.088 | 64.111 | 1.00 | 22.07 | B | C |
| ATOM | 840 | CB | VAL | B | 215 | 39.865 | 43.401 | 63.968 | 1.00 | 21.02 | B | C |
| ATOM | 841 | CG1 | VAL | B | 215 | 41.328 | 43.156 | 64.304 | 1.00 | 18.69 | B | C |
| ATOM | 842 | CG2 | VAL | B | 215 | 39.729 | 43.948 | 62.554 | 1.00 | 20.81 | B | C |
| ATOM | 843 | C | VAL | B | 215 | 39.282 | 41.566 | 65.528 | 1.00 | 24.98 | B | C |
| ATOM | 844 | O | VAL | B | 215 | 38.946 | 42.245 | 66.499 | 1.00 | 24.24 | B | O |
| ATOM | 845 | N | TYR | B | 216 | 39.829 | 40.355 | 65.641 | 1.00 | 25.63 | B | N |
| ATOM | 846 | CA | TYR | B | 216 | 40.101 | 39.752 | 66.941 | 1.00 | 23.89 | B | C |
| ATOM | 847 | CB | TYR | B | 216 | 39.628 | 38.306 | 66.967 | 1.00 | 22.31 | B | C |
| ATOM | 848 | CG | TYR | B | 216 | 38.199 | 38.150 | 67.429 | 1.00 | 24.76 | B | C |
| ATOM | 849 | CD1 | TYR | B | 216 | 37.897 | 37.488 | 68.618 | 1.00 | 22.21 | B | C |
| ATOM | 850 | CE1 | TYR | B | 216 | 36.580 | 37.328 | 69.040 | 1.00 | 23.30 | B | C |
| ATOM | 851 | CD2 | TYR | B | 216 | 37.145 | 38.653 | 66.670 | 1.00 | 26.09 | B | C |
| ATOM | 852 | CE2 | TYR | B | 216 | 35.819 | 38.500 | 67.085 | 1.00 | 26.56 | B | C |
| ATOM | 853 | CZ | TYR | B | 216 | 35.544 | 37.835 | 68.270 | 1.00 | 25.11 | B | C |
| ATOM | 854 | OH | TYR | B | 216 | 34.237 | 37.677 | 68.679 | 1.00 | 20.13 | B | O |
| ATOM | 855 | C | TYR | B | 216 | 41.590 | 39.806 | 67.236 | 1.00 | 23.96 | B | C |
| ATOM | 856 | O | TYR | B | 216 | 42.413 | 39.639 | 66.340 | 1.00 | 21.81 | B | O |
| ATOM | 857 | N | ILE | B | 217 | 41.930 | 40.040 | 68.500 | 1.00 | 28.39 | B | N |
| ATOM | 858 | CA | ILE | B | 217 | 43.329 | 40.126 | 68.911 | 1.00 | 31.87 | B | C |
| ATOM | 859 | CB | ILE | B | 217 | 43.585 | 41.382 | 69.770 | 1.00 | 31.69 | B | C |
| ATOM | 860 | CG2 | ILE | B | 217 | 45.078 | 41.586 | 69.954 | 1.00 | 33.32 | B | C |
| ATOM | 861 | CG1 | ILE | B | 217 | 42.973 | 42.615 | 69.101 | 1.00 | 32.37 | B | C |
| ATOM | 862 | CD1 | ILE | B | 217 | 42.065 | 43.417 | 70.017 | 1.00 | 30.66 | B | C |
| ATOM | 863 | C | ILE | B | 217 | 43.778 | 38.903 | 69.704 | 1.00 | 33.39 | B | C |
| ATOM | 864 | O | ILE | B | 217 | 43.177 | 38.551 | 70.725 | 1.00 | 33.81 | B | O |
| ATOM | 865 | N | TYR | B | 218 | 44.836 | 38.258 | 69.219 | 1.00 | 34.68 | B | N |
| ATOM | 866 | CA | TYR | B | 218 | 45.383 | 37.079 | 69.871 | 1.00 | 35.58 | B | C |
| ATOM | 867 | CB | TYR | B | 218 | 45.460 | 35.919 | 68.884 | 1.00 | 30.29 | B | C |
| ATOM | 868 | CG | TYR | B | 218 | 44.096 | 35.505 | 68.390 | 1.00 | 28.04 | B | C |
| ATOM | 869 | CD1 | TYR | B | 218 | 43.316 | 34.613 | 69.117 | 1.00 | 27.86 | B | C |
| ATOM | 870 | CE1 | TYR | B | 218 | 42.027 | 34.286 | 68.711 | 1.00 | 28.69 | B | C |
| ATOM | 871 | CD2 | TYR | B | 218 | 43.555 | 36.061 | 67.231 | 1.00 | 28.65 | B | C |
| ATOM | 872 | CE2 | TYR | B | 218 | 42.267 | 35.741 | 66.812 | 1.00 | 29.04 | B | C |
| ATOM | 873 | CZ | TYR | B | 218 | 41.508 | 34.855 | 67.561 | 1.00 | 30.56 | B | C |
| ATOM | 874 | OH | TYR | B | 218 | 40.229 | 34.544 | 67.163 | 1.00 | 31.12 | B | O |
| ATOM | 875 | C | TYR | B | 218 | 46.755 | 37.427 | 70.407 | 1.00 | 40.83 | B | C |
| ATOM | 876 | O | TYR | B | 218 | 47.632 | 37.872 | 69.665 | 1.00 | 40.20 | B | O |
| ATOM | 877 | N | ALA | B | 219 | 46.917 | 37.238 | 71.713 | 1.00 | 48.51 | B | N |
| ATOM | 878 | CA | ALA | B | 219 | 48.165 | 37.548 | 72.400 | 1.00 | 54.31 | B | C |
| ATOM | 879 | CB | ALA | B | 219 | 48.123 | 37.009 | 73.832 | 1.00 | 58.34 | B | C |
| ATOM | 880 | C | ALA | B | 219 | 49.366 | 36.984 | 71.667 | 1.00 | 55.29 | B | C |
| ATOM | 881 | O | ALA | B | 219 | 49.385 | 35.805 | 71.332 | 1.00 | 53.11 | B | O |
| ATOM | 882 | N | ASN | B | 220 | 50.347 | 37.857 | 71.427 | 1.00 | 58.77 | B | N |
| ATOM | 883 | CA | ASN | B | 220 | 51.610 | 37.548 | 70.746 | 1.00 | 62.15 | B | C |
| ATOM | 884 | CB | ASN | B | 220 | 52.791 | 38.019 | 71.614 | 1.00 | 64.60 | B | C |
| ATOM | 885 | CG | ASN | B | 220 | 52.342 | 38.725 | 72.896 | 1.00 | 67.65 | B | C |
| ATOM | 886 | OD1 | ASN | B | 220 | 52.733 | 39.865 | 73.157 | 1.00 | 70.87 | B | O |
| ATOM | 887 | ND2 | ASN | B | 220 | 51.523 | 38.047 | 73.699 | 1.00 | 68.66 | B | N |
| ATOM | 888 | C | ASN | B | 220 | 51.794 | 36.072 | 70.394 | 1.00 | 63.18 | B | C |
| ATOM | 889 | O | ASN | B | 220 | 52.822 | 35.463 | 70.716 | 1.00 | 63.24 | B | O |
| ATOM | 890 | N | GLU | B | 221 | 50.806 | 35.506 | 69.710 | 1.00 | 62.19 | B | N |
| ATOM | 891 | CA | GLU | B | 221 | 50.857 | 34.101 | 69.350 | 1.00 | 61.64 | B | C |
| ATOM | 892 | CB | GLU | B | 221 | 50.325 | 33.239 | 70.498 | 1.00 | 63.06 | B | C |
| ATOM | 893 | CG | GLU | B | 221 | 51.378 | 32.517 | 71.296 | 1.00 | 66.26 | B | C |
| ATOM | 894 | CD | GLU | B | 221 | 50.819 | 31.901 | 72.572 | 1.00 | 71.10 | B | C |
| ATOM | 895 | OE1 | GLU | B | 221 | 49.805 | 31.172 | 72.487 | 1.00 | 71.66 | B | O |
| ATOM | 896 | OE2 | GLU | B | 221 | 51.391 | 32.145 | 73.660 | 1.00 | 73.92 | B | O |
| ATOM | 897 | C | GLU | B | 221 | 50.014 | 33.834 | 68.128 | 1.00 | 61.22 | B | C |
| ATOM | 898 | O | GLU | B | 221 | 48.806 | 34.082 | 68.128 | 1.00 | 59.48 | B | O |
| ATOM | 899 | N | ALA | B | 222 | 50.653 | 33.325 | 67.082 | 1.00 | 60.16 | B | N |
| ATOM | 900 | CA | ALA | B | 222 | 49.927 | 32.980 | 65.877 | 1.00 | 59.02 | B | C |
| ATOM | 901 | CB | ALA | B | 222 | 50.896 | 32.627 | 64.755 | 1.00 | 58.48 | B | C |
| ATOM | 902 | C | ALA | B | 222 | 49.094 | 31.763 | 66.288 | 1.00 | 59.12 | B | C |
| ATOM | 903 | O | ALA | B | 222 | 48.482 | 31.093 | 65.459 | 1.00 | 57.30 | B | O |
| ATOM | 904 | N | ALA | B | 223 | 49.093 | 31.494 | 67.594 | 1.00 | 60.89 | B | N |
| ATOM | 905 | CA | ALA | B | 223 | 48.336 | 30.397 | 68.182 | 1.00 | 61.68 | B | C |
| ATOM | 906 | CB | ALA | B | 223 | 48.828 | 30.121 | 69.592 | 1.00 | 60.71 | B | C |
| ATOM | 907 | C | ALA | B | 223 | 46.861 | 30.799 | 68.205 | 1.00 | 64.14 | B | C |
| ATOM | 908 | O | ALA | B | 223 | 46.132 | 30.528 | 69.165 | 1.00 | 62.51 | B | O |
| ATOM | 909 | N | ALA | B | 224 | 46.445 | 31.482 | 67.142 | 1.00 | 64.65 | B | N |
| ATOM | 910 | CA | ALA | B | 224 | 45.065 | 31.908 | 66.984 | 1.00 | 63.55 | B | C |
| ATOM | 911 | CB | ALA | B | 224 | 44.977 | 33.043 | 65.977 | 1.00 | 61.42 | B | C |
| ATOM | 912 | C | ALA | B | 224 | 44.338 | 30.679 | 66.460 | 1.00 | 64.63 | B | C |
| ATOM | 913 | O | ALA | B | 224 | 43.118 | 30.697 | 66.273 | 1.00 | 63.90 | B | O |
| ATOM | 914 | N | GLY | B | 225 | 45.114 | 29.619 | 66.210 | 1.00 | 64.92 | B | N |
| ATOM | 915 | CA | GLY | B | 225 | 44.557 | 28.364 | 65.731 | 1.00 | 64.74 | B | C |
| ATOM | 916 | C | GLY | B | 225 | 43.501 | 27.971 | 66.738 | 1.00 | 65.55 | B | C |
| ATOM | 917 | O | GLY | B | 225 | 42.386 | 27.573 | 66.386 | 1.00 | 65.58 | B | O |
| ATOM | 918 | N | LYS | B | 226 | 43.870 | 28.080 | 68.010 | 1.00 | 64.14 | B | N |
| ATOM | 919 | CA | LYS | B | 226 | 42.941 | 27.807 | 69.088 | 1.00 | 64.20 | B | C |
| ATOM | 920 | CB | LYS | B | 226 | 43.681 | 27.316 | 70.336 | 1.00 | 65.46 | B | C |
| ATOM | 921 | CG | LYS | B | 226 | 42.907 | 26.283 | 71.149 | 1.00 | 67.38 | B | C |
| ATOM | 922 | CD | LYS | B | 226 | 43.222 | 24.861 | 70.690 | 1.00 | 70.32 | B | C |
| ATOM | 923 | CE | LYS | B | 226 | 42.955 | 23.839 | 71.792 | 1.00 | 69.91 | B | C |
| ATOM | 924 | NZ | LYS | B | 226 | 44.199 | 23.489 | 72.542 | 1.00 | 70.39 | B | N |
| ATOM | 925 | C | LYS | B | 226 | 42.330 | 29.182 | 69.338 | 1.00 | 63.82 | B | C |
| ATOM | 926 | O | LYS | B | 226 | 43.048 | 30.143 | 69.636 | 1.00 | 65.34 | B | O |
| ATOM | 927 | N | ASP | B | 227 | 41.017 | 29.288 | 69.177 | 1.00 | 60.65 | B | N |
| ATOM | 928 | CA | ASP | B | 227 | 40.340 | 30.556 | 69.387 | 1.00 | 57.10 | B | C |
| ATOM | 929 | CB | ASP | B | 227 | 38.852 | 30.407 | 69.092 | 1.00 | 59.46 | B | C |
| ATOM | 930 | CG | ASP | B | 227 | 38.414 | 31.236 | 67.904 | 1.00 | 62.82 | B | C |
| ATOM | 931 | OD1 | ASP | B | 227 | 38.157 | 30.640 | 66.831 | 1.00 | 61.95 | B | O |
| ATOM | 932 | OD2 | ASP | B | 227 | 38.332 | 32.480 | 68.048 | 1.00 | 61.80 | B | O |
| ATOM | 933 | C | ASP | B | 227 | 40.542 | 31.036 | 70.814 | 1.00 | 54.41 | B | C |
| ATOM | 934 | O | ASP | B | 227 | 39.660 | 30.893 | 71.659 | 1.00 | 54.99 | B | O |
| ATOM | 935 | N | GLU | B | 228 | 41.712 | 31.606 | 71.078 | 1.00 | 51.59 | B | N |
| ATOM | 936 | CA | GLU | B | 228 | 42.038 | 32.103 | 72.406 | 1.00 | 48.65 | B | C |
| ATOM | 937 | CB | GLU | B | 228 | 43.126 | 31.240 | 73.043 | 1.00 | 50.66 | B | C |
| ATOM | 938 | CG | GLU | B | 228 | 42.585 | 30.009 | 73.753 | 1.00 | 54.46 | B | C |
| ATOM | 939 | CD | GLU | B | 228 | 43.554 | 28.835 | 73.734 | 1.00 | 56.19 | B | C |
| ATOM | 940 | OE1 | GLU | B | 228 | 44.780 | 29.064 | 73.857 | 1.00 | 57.01 | B | O |
| ATOM | 941 | OE2 | GLU | B | 228 | 43.083 | 27.685 | 73.600 | 1.00 | 55.11 | B | O |
| ATOM | 942 | C | GLU | B | 228 | 42.507 | 33.542 | 72.320 | 1.00 | 45.44 | B | C |
| ATOM | 943 | O | GLU | B | 228 | 43.688 | 33.840 | 72.527 | 1.00 | 46.20 | B | O |
| ATOM | 944 | N | PRO | B | 229 | 41.583 | 34.460 | 72.004 | 1.00 | 41.18 | B | N |
| ATOM | 945 | CD | PRO | B | 229 | 40.156 | 34.226 | 71.720 | 1.00 | 38.72 | B | C |
| ATOM | 946 | CA | PRO | B | 229 | 41.941 | 35.875 | 71.898 | 1.00 | 38.36 | B | C |
| ATOM | 947 | CB | PRO | B | 229 | 40.693 | 36.520 | 71.308 | 1.00 | 38.59 | B | C |
| ATOM | 948 | CG | PRO | B | 229 | 39.579 | 35.603 | 71.690 | 1.00 | 36.80 | B | C |
| ATOM | 949 | C | PRO | B | 229 | 42.305 | 36.456 | 73.250 | 1.00 | 34.98 | B | C |
| ATOM | 950 | O | PRO | B | 229 | 41.965 | 35.892 | 74.279 | 1.00 | 31.89 | B | O |
| ATOM | 951 | N | LYS | B | 230 | 43.009 | 37.579 | 73.238 | 1.00 | 36.16 | B | N |
| ATOM | 952 | CA | LYS | B | 230 | 43.400 | 38.236 | 74.474 | 1.00 | 39.59 | B | C |
| ATOM | 953 | CB | LYS | B | 230 | 44.173 | 39.521 | 74.178 | 1.00 | 39.86 | B | C |
| ATOM | 954 | CG | LYS | B | 230 | 45.679 | 39.357 | 74.185 | 1.00 | 40.47 | B | C |
| ATOM | 955 | CD | LYS | B | 230 | 46.230 | 39.507 | 75.585 | 1.00 | 45.97 | B | C |
| ATOM | 956 | CE | LYS | B | 230 | 47.342 | 40.537 | 75.631 | 1.00 | 48.78 | B | C |
| ATOM | 957 | NZ | LYS | B | 230 | 48.682 | 39.879 | 75.659 | 1.00 | 53.58 | B | N |
| ATOM | 958 | C | LYS | B | 230 | 42.123 | 38.580 | 75.222 | 1.00 | 41.82 | B | C |
| ATOM | 959 | O | LYS | B | 230 | 41.152 | 39.036 | 74.616 | 1.00 | 44.73 | B | O |
| ATOM | 960 | N | PRO | B | 231 | 42.102 | 38.358 | 76.548 | 1.00 | 41.90 | B | N |
| ATOM | 961 | CD | PRO | B | 231 | 43.198 | 37.808 | 77.366 | 1.00 | 42.17 | B | C |
| ATOM | 962 | CA | PRO | B | 231 | 40.923 | 38.657 | 77.364 | 1.00 | 40.40 | B | C |
| ATOM | 963 | CB | PRO | B | 231 | 41.474 | 38.668 | 78.782 | 1.00 | 40.68 | B | C |
| ATOM | 964 | CG | PRO | B | 231 | 42.569 | 37.661 | 78.730 | 1.00 | 41.70 | B | C |
| ATOM | 965 | C | PRO | B | 231 | 40.303 | 39.987 | 76.966 | 1.00 | 38.73 | B | C |
| ATOM | 966 | O | PRO | B | 231 | 40.980 | 41.017 | 76.931 | 1.00 | 36.46 | B | O |
| ATOM | 967 | N | LEU | B | 232 | 39.011 | 39.948 | 76.661 | 1.00 | 38.05 | B | N |
| ATOM | 968 | CA | LEU | B | 232 | 38.286 | 41.139 | 76.243 | 1.00 | 37.77 | B | C |
| ATOM | 969 | CB | LEU | B | 232 | 38.950 | 41.722 | 74.995 | 1.00 | 38.48 | B | C |
| ATOM | 970 | CG | LEU | B | 232 | 38.646 | 43.155 | 74.568 | 1.00 | 39.63 | B | C |
| ATOM | 971 | CD1 | LEU | B | 232 | 39.905 | 43.793 | 73.984 | 1.00 | 38.26 | B | C |
| ATOM | 972 | CD2 | LEU | B | 232 | 37.525 | 43.146 | 73.539 | 1.00 | 41.50 | B | C |
| ATOM | 973 | C | LEU | B | 232 | 36.827 | 40.805 | 75.944 | 1.00 | 37.52 | B | C |
| ATOM | 974 | O | LEU | B | 232 | 36.497 | 39.694 | 75.530 | 1.00 | 36.42 | B | O |
| ATOM | 975 | N | LEU | B | 233 | 35.950 | 41.771 | 76.178 | 1.00 | 38.73 | B | N |
| ATOM | 976 | CA | LEU | B | 233 | 34.530 | 41.588 | 75.905 | 1.00 | 38.31 | B | C |
| ATOM | 977 | CB | LEU | B | 233 | 33.690 | 42.498 | 76.807 | 1.00 | 41.80 | B | C |
| ATOM | 978 | CG | LEU | B | 233 | 33.956 | 44.001 | 76.638 | 1.00 | 46.85 | B | C |
| ATOM | 979 | CD1 | LEU | B | 233 | 32.742 | 44.792 | 77.135 | 1.00 | 45.67 | B | C |
| ATOM | 980 | CD2 | LEU | B | 233 | 35.245 | 44.400 | 77.385 | 1.00 | 45.54 | B | C |
| ATOM | 981 | C | LEU | B | 233 | 34.316 | 41.969 | 74.443 | 1.00 | 36.60 | B | C |
| ATOM | 982 | O | LEU | B | 233 | 34.486 | 43.129 | 74.061 | 1.00 | 35.37 | B | O |
| ATOM | 983 | N | TYR | B | 234 | 33.972 | 40.987 | 73.621 | 1.00 | 34.06 | B | N |
| ATOM | 984 | CA | TYR | B | 234 | 33.746 | 41.236 | 72.208 | 1.00 | 30.70 | B | C |
| ATOM | 985 | CB | TYR | B | 234 | 34.324 | 40.085 | 71.374 | 1.00 | 27.74 | B | C |
| ATOM | 986 | CG | TYR | B | 234 | 35.834 | 40.049 | 71.360 | 1.00 | 28.95 | B | C |
| ATOM | 987 | CD1 | TYR | B | 234 | 36.542 | 39.485 | 72.421 | 1.00 | 31.33 | B | C |
| ATOM | 988 | CE1 | TYR | B | 234 | 37.943 | 39.461 | 72.430 | 1.00 | 30.74 | B | C |
| ATOM | 989 | CD2 | TYR | B | 234 | 36.565 | 40.593 | 70.296 | 1.00 | 28.25 | B | C |
| ATOM | 990 | CE2 | TYR | B | 234 | 37.970 | 40.574 | 70.296 | 1.00 | 28.66 | B | C |
| ATOM | 991 | CZ | TYR | B | 234 | 38.649 | 40.008 | 71.369 | 1.00 | 29.98 | B | C |
| ATOM | 992 | OH | TYR | B | 234 | 40.027 | 39.996 | 71.401 | 1.00 | 30.31 | B | O |
| ATOM | 993 | C | TYR | B | 234 | 32.250 | 41.379 | 71.951 | 1.00 | 29.41 | B | C |
| ATOM | 994 | O | TYR | B | 234 | 31.430 | 41.019 | 72.798 | 1.00 | 29.52 | B | O |
| ATOM | 995 | N | PRO | B | 235 | 31.875 | 41.933 | 70.789 | 1.00 | 27.60 | B | N |
| ATOM | 996 | CD | PRO | B | 235 | 32.747 | 42.453 | 69.722 | 1.00 | 27.29 | B | C |
| ATOM | 997 | CA | PRO | B | 235 | 30.457 | 42.097 | 70.465 | 1.00 | 26.88 | B | C |
| ATOM | 998 | CB | PRO | B | 235 | 30.475 | 42.688 | 69.055 | 1.00 | 27.25 | B | C |
| ATOM | 999 | CG | PRO | B | 235 | 31.826 | 43.312 | 68.922 | 1.00 | 25.79 | B | C |
| ATOM | 1000 | C | PRO | B | 235 | 29.737 | 40.754 | 70.499 | 1.00 | 24.86 | B | C |
| ATOM | 1001 | O | PRO | B | 235 | 30.308 | 39.735 | 70.130 | 1.00 | 26.65 | B | O |
| ATOM | 1002 | N | ASN | B | 236 | 28.487 | 40.757 | 70.946 | 1.00 | 24.53 | B | N |
| ATOM | 1003 | CA | ASN | B | 236 | 27.687 | 39.540 | 71.015 | 1.00 | 25.58 | B | C |
| ATOM | 1004 | CB | ASN | B | 236 | 27.203 | 39.320 | 72.443 | 1.00 | 25.49 | B | C |
| ATOM | 1005 | CG | ASN | B | 236 | 26.503 | 37.999 | 72.620 | 1.00 | 27.68 | B | C |
| ATOM | 1006 | OD1 | ASN | B | 236 | 25.721 | 37.578 | 71.768 | 1.00 | 28.92 | B | O |
| ATOM | 1007 | ND2 | ASN | B | 236 | 26.777 | 37.333 | 73.735 | 1.00 | 28.44 | B | N |
| ATOM | 1008 | C | ASN | B | 236 | 26.493 | 39.704 | 70.077 | 1.00 | 25.97 | B | C |
| ATOM | 1009 | O | ASN | B | 236 | 25.489 | 40.325 | 70.440 | 1.00 | 25.41 | B | O |
| ATOM | 1010 | N | MET | B | 237 | 26.604 | 39.141 | 68.877 | 1.00 | 23.87 | B | N |
| ATOM | 1011 | CA | MET | B | 237 | 25.550 | 39.263 | 67.882 | 1.00 | 25.71 | B | C |
| ATOM | 1012 | CB | MET | B | 237 | 25.981 | 38.640 | 66.559 | 1.00 | 28.06 | B | C |
| ATOM | 1013 | CG | MET | B | 237 | 25.191 | 39.188 | 65.382 | 1.00 | 32.90 | B | C |
| ATOM | 1014 | SD | MET | B | 237 | 25.676 | 38.470 | 63.812 | 1.00 | 40.21 | B | S |
| ATOM | 1015 | CE | MET | B | 237 | 24.786 | 36.887 | 63.871 | 1.00 | 37.81 | B | C |
| ATOM | 1016 | C | MET | B | 237 | 24.192 | 38.708 | 68.261 | 1.00 | 24.05 | B | C |
| ATOM | 1017 | O | MET | B | 237 | 23.176 | 39.310 | 67.939 | 1.00 | 25.10 | B | O |
| ATOM | 1018 | N | GLU | B | 238 | 24.151 | 37.562 | 68.924 | 1.00 | 24.91 | B | N |
| ATOM | 1019 | CA | GLU | B | 238 | 22.864 | 37.006 | 69.311 | 1.00 | 28.14 | B | C |
| ATOM | 1020 | CB | GLU | B | 238 | 23.032 | 35.654 | 70.002 | 1.00 | 33.30 | B | C |
| ATOM | 1021 | CG | GLU | B | 238 | 21.716 | 34.893 | 70.125 | 1.00 | 44.96 | B | C |
| ATOM | 1022 | CD | GLU | B | 238 | 21.814 | 33.645 | 70.991 | 1.00 | 49.67 | B | C |
| ATOM | 1023 | OE1 | GLU | B | 238 | 20.798 | 33.290 | 71.633 | 1.00 | 50.79 | B | O |
| ATOM | 1024 | OE2 | GLU | B | 238 | 22.900 | 33.022 | 71.027 | 1.00 | 52.11 | B | O |
| ATOM | 1025 | C | GLU | B | 238 | 22.163 | 37.974 | 70.256 | 1.00 | 27.25 | B | C |
| ATOM | 1026 | O | GLU | B | 238 | 20.966 | 38.232 | 70.131 | 1.00 | 26.03 | B | O |
| ATOM | 1027 | N | GLU | B | 239 | 22.924 | 38.507 | 71.201 | 1.00 | 24.20 | B | N |
| ATOM | 1028 | CA | GLU | B | 239 | 22.397 | 39.451 | 72.166 | 1.00 | 24.98 | B | C |
| ATOM | 1029 | CB | GLU | B | 239 | 23.493 | 39.818 | 73.171 | 1.00 | 28.15 | B | C |
| ATOM | 1030 | CG | GLU | B | 239 | 23.070 | 40.808 | 74.242 | 1.00 | 31.00 | B | C |
| ATOM | 1031 | CD | GLU | B | 239 | 24.231 | 41.239 | 75.116 | 1.00 | 33.65 | B | C |
| ATOM | 1032 | OE1 | GLU | B | 239 | 24.159 | 42.340 | 75.703 | 1.00 | 33.02 | B | O |
| ATOM | 1033 | OE2 | GLU | B | 239 | 25.217 | 40.477 | 75.213 | 1.00 | 33.96 | B | O |
| ATOM | 1034 | C | GLU | B | 239 | 21.912 | 40.703 | 71.439 | 1.00 | 24.81 | B | C |
| ATOM | 1035 | O | GLU | B | 239 | 20.850 | 41.242 | 71.740 | 1.00 | 23.15 | B | O |
| ATOM | 1036 | N | PHE | B | 240 | 22.702 | 41.158 | 70.473 | 1.00 | 23.58 | B | N |
| ATOM | 1037 | CA | PHE | B | 240 | 22.359 | 42.347 | 69.706 | 1.00 | 22.65 | B | C |
| ATOM | 1038 | CB | PHE | B | 240 | 23.473 | 42.685 | 68.723 | 1.00 | 20.49 | B | C |
| ATOM | 1039 | CG | PHE | B | 240 | 23.190 | 43.902 | 67.898 | 1.00 | 19.26 | B | C |
| ATOM | 1040 | CD1 | PHE | B | 240 | 22.318 | 43.840 | 66.819 | 1.00 | 20.15 | B | C |
| ATOM | 1041 | CD2 | PHE | B | 240 | 23.795 | 45.115 | 68.200 | 1.00 | 19.87 | B | C |
| ATOM | 1042 | CE1 | PHE | B | 240 | 22.052 | 44.975 | 66.048 | 1.00 | 19.84 | B | C |
| ATOM | 1043 | CE2 | PHE | B | 240 | 23.538 | 46.251 | 67.440 | 1.00 | 20.62 | B | C |
| ATOM | 1044 | CZ | PHE | B | 240 | 22.663 | 46.179 | 66.360 | 1.00 | 18.91 | B | C |
| ATOM | 1045 | C | PHE | B | 240 | 21.057 | 42.185 | 68.934 | 1.00 | 22.23 | B | C |
| ATOM | 1046 | O | PHE | B | 240 | 20.201 | 43.070 | 68.947 | 1.00 | 21.70 | B | O |
| ATOM | 1047 | N | LEU | B | 241 | 20.920 | 41.059 | 68.244 | 1.00 | 21.91 | B | N |
| ATOM | 1048 | CA | LEU | B | 241 | 19.719 | 40.793 | 67.469 | 1.00 | 21.89 | B | C |
| ATOM | 1049 | CB | LEU | B | 241 | 19.891 | 39.508 | 66.658 | 1.00 | 20.87 | B | C |
| ATOM | 1050 | CG | LEU | B | 241 | 20.920 | 39.594 | 65.525 | 1.00 | 21.34 | B | C |
| ATOM | 1051 | CD1 | LEU | B | 241 | 21.241 | 38.199 | 65.003 | 1.00 | 21.31 | B | C |
| ATOM | 1052 | CD2 | LEU | B | 241 | 20.378 | 40.472 | 64.418 | 1.00 | 19.12 | B | C |
| ATOM | 1053 | C | LEU | B | 241 | 18.501 | 40.682 | 68.379 | 1.00 | 23.08 | B | C |
| ATOM | 1054 | O | LEU | B | 241 | 17.378 | 40.975 | 67.968 | 1.00 | 23.39 | B | O |
| ATOM | 1055 | N | ASP | B | 242 | 18.723 | 40.271 | 69.621 | 1.00 | 23.49 | B | N |
| ATOM | 1056 | CA | ASP | B | 242 | 17.622 | 40.140 | 70.570 | 1.00 | 25.89 | B | C |
| ATOM | 1057 | CB | ASP | B | 242 | 18.081 | 39.394 | 71.828 | 1.00 | 31.81 | B | C |
| ATOM | 1058 | CG | ASP | B | 242 | 18.265 | 37.906 | 71.589 | 1.00 | 39.05 | B | C |
| ATOM | 1059 | OD1 | ASP | B | 242 | 17.998 | 37.442 | 70.456 | 1.00 | 42.61 | B | O |
| ATOM | 1060 | OD2 | ASP | B | 242 | 18.680 | 37.200 | 72.536 | 1.00 | 42.92 | B | O |
| ATOM | 1061 | C | ASP | B | 242 | 17.104 | 41.514 | 70.966 | 1.00 | 24.11 | B | C |
| ATOM | 1062 | O | ASP | B | 242 | 15.893 | 41.750 | 71.000 | 1.00 | 21.41 | B | O |
| ATOM | 1063 | N | ASP | B | 243 | 18.034 | 42.414 | 71.273 | 1.00 | 23.12 | B | N |
| ATOM | 1064 | CA | ASP | B | 243 | 17.681 | 43.766 | 71.677 | 1.00 | 21.59 | B | C |
| ATOM | 1065 | CB | ASP | B | 243 | 18.925 | 44.532 | 72.142 | 1.00 | 22.59 | B | C |
| ATOM | 1066 | CG | ASP | B | 243 | 19.456 | 44.034 | 73.481 | 1.00 | 21.06 | B | C |
| ATOM | 1067 | OD1 | ASP | B | 243 | 18.671 | 43.450 | 74.249 | 1.00 | 21.09 | B | O |
| ATOM | 1068 | OD2 | ASP | B | 243 | 20.663 | 44.228 | 73.763 | 1.00 | 19.92 | B | O |
| ATOM | 1069 | C | ASP | B | 243 | 17.046 | 44.491 | 70.502 | 1.00 | 21.35 | B | C |
| ATOM | 1070 | O | ASP | B | 243 | 16.104 | 45.264 | 70.676 | 1.00 | 19.48 | B | O |
| ATOM | 1071 | N | MET | B | 244 | 17.560 | 44.224 | 69.305 | 1.00 | 21.35 | B | N |
| ATOM | 1072 | CA | MET | B | 244 | 17.050 | 44.863 | 68.098 | 1.00 | 19.39 | B | C |
| ATOM | 1073 | CB | MET | B | 244 | 17.921 | 44.510 | 66.902 | 1.00 | 19.77 | B | C |
| ATOM | 1074 | CG | MET | B | 244 | 17.345 | 44.984 | 65.588 | 1.00 | 19.12 | B | C |
| ATOM | 1075 | SD | MET | B | 244 | 18.299 | 44.400 | 64.188 | 1.00 | 22.71 | B | S |
| ATOM | 1076 | CE | MET | B | 244 | 17.615 | 42.765 | 63.981 | 1.00 | 17.07 | B | C |
| ATOM | 1077 | C | MET | B | 244 | 15.623 | 44.451 | 67.801 | 1.00 | 19.45 | B | C |
| ATOM | 1078 | O | MET | B | 244 | 14.786 | 45.283 | 67.457 | 1.00 | 17.22 | B | O |
| ATOM | 1079 | N | ASN | B | 245 | 15.350 | 43.157 | 67.929 | 1.00 | 19.47 | B | N |
| ATOM | 1080 | CA | ASN | B | 245 | 14.020 | 42.636 | 67.660 | 1.00 | 20.33 | B | C |
| ATOM | 1081 | CB | ASN | B | 245 | 14.043 | 41.117 | 67.712 | 1.00 | 21.11 | B | C |
| ATOM | 1082 | CG | ASN | B | 245 | 14.738 | 40.517 | 66.516 | 1.00 | 23.70 | B | C |
| ATOM | 1083 | OD1 | ASN | B | 245 | 14.470 | 40.902 | 65.379 | 1.00 | 26.12 | B | O |
| ATOM | 1084 | ND2 | ASN | B | 245 | 15.644 | 39.576 | 66.762 | 1.00 | 25.27 | B | N |
| ATOM | 1085 | C | ASN | B | 245 | 13.007 | 43.180 | 68.653 | 1.00 | 21.08 | B | C |
| ATOM | 1086 | O | ASN | B | 245 | 11.813 | 43.282 | 68.353 | 1.00 | 20.25 | B | O |
| ATOM | 1087 | N | PHE | B | 246 | 13.495 | 43.523 | 69.840 | 1.00 | 20.79 | B | N |
| ATOM | 1088 | CA | PHE | B | 246 | 12.651 | 44.075 | 70.883 | 1.00 | 19.49 | B | C |
| ATOM | 1089 | CB | PHE | B | 246 | 13.397 | 44.117 | 72.221 | 1.00 | 19.51 | B | C |
| ATOM | 1090 | CG | PHE | B | 246 | 12.810 | 45.097 | 73.193 | 1.00 | 21.84 | B | C |
| ATOM | 1091 | CD1 | PHE | B | 246 | 13.377 | 46.351 | 73.366 | 1.00 | 19.93 | B | C |
| ATOM | 1092 | CD2 | PHE | B | 246 | 11.652 | 44.784 | 73.896 | 1.00 | 24.53 | B | C |
| ATOM | 1093 | CE1 | PHE | B | 246 | 12.803 | 47.273 | 74.213 | 1.00 | 21.11 | B | C |
| ATOM | 1094 | CE2 | PHE | B | 246 | 11.072 | 45.703 | 74.748 | 1.00 | 22.42 | B | C |
| ATOM | 1095 | CZ | PHE | B | 246 | 11.648 | 46.949 | 74.907 | 1.00 | 22.40 | B | C |
| ATOM | 1096 | C | PHE | B | 246 | 12.263 | 45.497 | 70.488 | 1.00 | 18.18 | B | C |
| ATOM | 1097 | O | PHE | B | 246 | 11.099 | 45.882 | 70.572 | 1.00 | 18.64 | B | O |
| ATOM | 1098 | N | LEU | B | 247 | 13.252 | 46.278 | 70.073 | 1.00 | 14.46 | B | N |
| ATOM | 1099 | CA | LEU | B | 247 | 13.004 | 47.649 | 69.670 | 1.00 | 17.19 | B | C |
| ATOM | 1100 | CB | LEU | B | 247 | 14.330 | 48.349 | 69.363 | 1.00 | 15.57 | B | C |
| ATOM | 1101 | CG | LEU | B | 247 | 15.204 | 48.662 | 70.584 | 1.00 | 11.81 | B | C |
| ATOM | 1102 | CD1 | LEU | B | 247 | 16.489 | 49.351 | 70.153 | 1.00 | 8.09 | B | C |
| ATOM | 1103 | CD2 | LEU | B | 247 | 14.429 | 49.546 | 71.539 | 1.00 | 7.73 | B | C |
| ATOM | 1104 | C | LEU | B | 247 | 12.090 | 47.675 | 68.446 | 1.00 | 20.03 | B | C |
| ATOM | 1105 | O | LEU | B | 247 | 11.217 | 48.538 | 68.326 | 1.00 | 20.02 | B | O |
| ATOM | 1106 | N | LEU | B | 248 | 12.286 | 46.719 | 67.542 | 1.00 | 22.31 | B | N |
| ATOM | 1107 | CA | LEU | B | 248 | 11.472 | 46.647 | 66.337 | 1.00 | 23.06 | B | C |
| ATOM | 1108 | CB | LEU | B | 248 | 11.928 | 45.493 | 65.448 | 1.00 | 23.86 | B | C |
| ATOM | 1109 | CG | LEU | B | 248 | 12.430 | 45.831 | 64.039 | 1.00 | 28.05 | B | C |
| ATOM | 1110 | CD1 | LEU | B | 248 | 13.038 | 47.236 | 63.999 | 1.00 | 26.99 | B | C |
| ATOM | 1111 | CD2 | LEU | B | 248 | 13.467 | 44.788 | 63.624 | 1.00 | 26.06 | B | C |
| ATOM | 1112 | C | LEU | B | 248 | 10.019 | 46.451 | 66.717 | 1.00 | 22.03 | B | C |
| ATOM | 1113 | O | LEU | B | 248 | 9.132 | 47.083 | 66.155 | 1.00 | 24.50 | B | O |
| ATOM | 1114 | N | ALA | B | 249 | 9.777 | 45.572 | 67.678 | 1.00 | 20.93 | B | N |
| ATOM | 1115 | CA | ALA | B | 249 | 8.417 | 45.300 | 68.120 | 1.00 | 21.10 | B | C |
| ATOM | 1116 | CB | ALA | B | 249 | 8.413 | 44.103 | 69.071 | 1.00 | 17.39 | B | C |
| ATOM | 1117 | C | ALA | B | 249 | 7.832 | 46.530 | 68.812 | 1.00 | 21.64 | B | C |
| ATOM | 1118 | O | ALA | B | 249 | 6.684 | 46.924 | 68.573 | 1.00 | 22.02 | B | O |
| ATOM | 1119 | N | LEU | B | 250 | 8.645 | 47.138 | 69.665 | 1.00 | 21.75 | B | N |
| ATOM | 1120 | CA | LEU | B | 250 | 8.240 | 48.308 | 70.420 | 1.00 | 21.30 | B | C |
| ATOM | 1121 | CB | LEU | B | 250 | 9.396 | 48.774 | 71.298 | 1.00 | 18.50 | B | C |
| ATOM | 1122 | CG | LEU | B | 250 | 9.047 | 49.826 | 72.345 | 1.00 | 17.05 | B | C |
| ATOM | 1123 | CD1 | LEU | B | 250 | 8.225 | 49.198 | 73.449 | 1.00 | 11.30 | B | C |
| ATOM | 1124 | CD2 | LEU | B | 250 | 10.326 | 50.435 | 72.890 | 1.00 | 14.44 | B | C |
| ATOM | 1125 | C | LEU | B | 250 | 7.748 | 49.469 | 69.562 | 1.00 | 22.44 | B | C |
| ATOM | 1126 | O | LEU | B | 250 | 6.595 | 49.874 | 69.685 | 1.00 | 24.56 | B | O |
| ATOM | 1127 | N | ILE | B | 251 | 8.606 | 50.005 | 68.697 | 1.00 | 21.71 | B | N |
| ATOM | 1128 | CA | ILE | B | 251 | 8.210 | 51.142 | 67.864 | 1.00 | 22.34 | B | C |
| ATOM | 1129 | CB | ILE | B | 251 | 9.352 | 51.583 | 66.909 | 1.00 | 21.27 | B | C |
| ATOM | 1130 | CG2 | ILE | B | 251 | 10.664 | 51.689 | 67.676 | 1.00 | 19.54 | B | C |
| ATOM | 1131 | CG1 | ILE | B | 251 | 9.479 | 50.600 | 65.747 | 1.00 | 21.82 | B | C |
| ATOM | 1132 | CD1 | ILE | B | 251 | 10.771 | 50.737 | 64.967 | 1.00 | 24.05 | B | C |
| ATOM | 1133 | C | ILE | B | 251 | 6.944 | 50.905 | 67.042 | 1.00 | 23.14 | B | C |
| ATOM | 1134 | O | ILE | B | 251 | 6.357 | 51.851 | 66.513 | 1.00 | 24.35 | B | O |
| ATOM | 1135 | N | ALA | B | 252 | 6.511 | 49.653 | 66.946 | 1.00 | 22.74 | B | N |
| ATOM | 1136 | CA | ALA | B | 252 | 5.310 | 49.337 | 66.180 | 1.00 | 24.76 | B | C |
| ATOM | 1137 | CB | ALA | B | 252 | 5.590 | 48.190 | 65.212 | 1.00 | 25.61 | B | C |
| ATOM | 1138 | C | ALA | B | 252 | 4.122 | 48.987 | 67.070 | 1.00 | 24.97 | B | C |
| ATOM | 1139 | O | ALA | B | 252 | 3.054 | 48.635 | 66.572 | 1.00 | 26.86 | B | O |
| ATOM | 1140 | N | GLN | B | 253 | 4.309 | 49.094 | 68.381 | 1.00 | 26.54 | B | N |
| ATOM | 1141 | CA | GLN | B | 253 | 3.250 | 48.796 | 69.342 | 1.00 | 26.45 | B | C |
| ATOM | 1142 | CB | GLN | B | 253 | 3.848 | 48.544 | 70.714 | 1.00 | 29.30 | B | C |
| ATOM | 1143 | CG | GLN | B | 253 | 3.548 | 47.178 | 71.267 | 1.00 | 33.94 | B | C |
| ATOM | 1144 | CD | GLN | B | 253 | 4.496 | 46.808 | 72.379 | 1.00 | 36.17 | B | C |
| ATOM | 1145 | OE1 | GLN | B | 253 | 5.333 | 45.919 | 72.227 | 1.00 | 38.40 | B | O |
| ATOM | 1146 | NE2 | GLN | B | 253 | 4.376 | 47.494 | 73.510 | 1.00 | 38.28 | B | N |
| ATOM | 1147 | C | GLN | B | 253 | 2.251 | 49.935 | 69.445 | 1.00 | 26.52 | B | C |
| ATOM | 1148 | O | GLN | B | 253 | 2.614 | 51.066 | 69.760 | 1.00 | 25.99 | B | O |
| ATOM | 1149 | N | GLY | B | 254 | 0.985 | 49.621 | 69.198 | 1.00 | 26.91 | B | N |
| ATOM | 1150 | CA | GLY | B | 254 | −0.063 | 50.626 | 69.237 | 1.00 | 23.35 | B | C |
| ATOM | 1151 | C | GLY | B | 254 | −0.049 | 51.562 | 70.429 | 1.00 | 22.46 | B | C |
| ATOM | 1152 | 0 | GLY | B | 254 | 0.078 | 52.774 | 70.257 | 1.00 | 24.32 | B | O |
| ATOM | 1153 | N | PRO | B | 255 | −0.186 | 51.034 | 71.655 | 1.00 | 20.44 | B | N |
| ATOM | 1154 | CD | PRO | B | 255 | −0.363 | 49.603 | 71.956 | 1.00 | 18.41 | B | C |
| ATOM | 1155 | CA | PRO | B | 255 | −0.193 | 51.846 | 72.874 | 1.00 | 18.00 | B | C |
| ATOM | 1156 | CB | PRO | B | 255 | −0.330 | 50.815 | 73.988 | 1.00 | 17.39 | B | C |
| ATOM | 1157 | CG | PRO | B | 255 | −0.940 | 49.628 | 73.327 | 1.00 | 17.66 | B | C |
| ATOM | 1158 | C | PRO | B | 255 | 1.026 | 52.738 | 73.064 | 1.00 | 19.53 | B | C |
| ATOM | 1159 | O | PRO | B | 255 | 0.896 | 53.879 | 73.499 | 1.00 | 23.27 | B | O |
| ATOM | 1160 | N | VAL | B | 256 | 2.212 | 52.228 | 72.750 | 1.00 | 19.35 | B | N |
| ATOM | 1161 | CA | VAL | B | 256 | 3.430 | 53.019 | 72.896 | 1.00 | 17.67 | B | C |
| ATOM | 1162 | CB | VAL | B | 256 | 4.687 | 52.156 | 72.690 | 1.00 | 16.57 | B | C |
| ATOM | 1163 | CG1 | VAL | B | 256 | 5.927 | 52.992 | 72.931 | 1.00 | 11.80 | B | C |
| ATOM | 1164 | CG2 | VAL | B | 256 | 4.656 | 50.961 | 73.638 | 1.00 | 11.49 | B | C |
| ATOM | 1165 | C | VAL | B | 256 | 3.449 | 54.156 | 71.882 | 1.00 | 20.60 | B | C |
| ATOM | 1166 | O | VAL | B | 256 | 3.956 | 55.246 | 72.161 | 1.00 | 22.68 | B | O |
| ATOM | 1167 | N | LYS | B | 257 | 2.894 | 53.895 | 70.702 | 1.00 | 21.63 | B | N |
| ATOM | 1168 | CA | LYS | B | 257 | 2.834 | 54.892 | 69.637 | 1.00 | 20.06 | B | C |
| ATOM | 1169 | CB | LYS | B | 257 | 2.241 | 54.278 | 68.362 | 1.00 | 23.46 | B | C |
| ATOM | 1170 | CG | LYS | B | 257 | 3.235 | 54.070 | 67.234 | 1.00 | 23.46 | B | C |
| ATOM | 1171 | CD | LYS | B | 257 | 3.043 | 52.721 | 66.578 | 1.00 | 24.30 | B | C |
| ATOM | 1172 | CE | LYS | B | 257 | 2.114 | 52.820 | 65.380 | 1.00 | 29.74 | B | C |
| ATOM | 1173 | NZ | LYS | B | 257 | 1.077 | 51.734 | 65.370 | 1.00 | 34.20 | B | N |
| ATOM | 1174 | C | LYS | B | 257 | 1.951 | 56.034 | 70.094 | 1.00 | 18.74 | B | C |
| ATOM | 1175 | O | LYS | B | 257 | 2.286 | 57.204 | 69.910 | 1.00 | 18.08 | B | O |
| ATOM | 1176 | N | THR | B | 258 | 0.819 | 55.683 | 70.695 | 1.00 | 17.60 | B | N |
| ATOM | 1177 | CA | THR | B | 258 | −0.128 | 56.679 | 71.179 | 1.00 | 18.35 | B | C |
| ATOM | 1178 | CB | THR | B | 258 | −1.421 | 56.013 | 71.633 | 1.00 | 19.62 | B | C |
| ATOM | 1179 | OG1 | THR | B | 258 | −1.977 | 55.279 | 70.537 | 1.00 | 23.78 | B | O |
| ATOM | 1180 | CG2 | THR | B | 258 | −2.424 | 57.060 | 72.092 | 1.00 | 23.16 | B | C |
| ATOM | 1181 | C | THR | B | 258 | 0.427 | 57.520 | 72.329 | 1.00 | 18.24 | B | C |
| ATOM | 1182 | O | THR | B | 258 | 0.354 | 58.749 | 72.297 | 1.00 | 19.69 | B | O |
| ATOM | 1183 | N | TYR | B | 259 | 0.983 | 56.864 | 73.342 | 1.00 | 15.87 | B | N |
| ATOM | 1184 | CA | TYR | B | 259 | 1.543 | 57.581 | 74.480 | 1.00 | 12.67 | B | C |
| ATOM | 1185 | CB | TYR | B | 259 | 2.122 | 56.592 | 75.498 | 1.00 | 14.72 | B | C |
| ATOM | 1186 | CG | TYR | B | 259 | 2.786 | 57.260 | 76.681 | 1.00 | 18.96 | B | C |
| ATOM | 1187 | CD1 | TYR | B | 259 | 4.175 | 57.373 | 76.751 | 1.00 | 18.78 | B | C |
| ATOM | 1188 | CE1 | TYR | B | 259 | 4.792 | 58.004 | 77.826 | 1.00 | 19.99 | B | C |
| ATOM | 1189 | CD2 | TYR | B | 259 | 2.024 | 57.801 | 77.725 | 1.00 | 17.66 | B | C |
| ATOM | 1190 | CE2 | TYR | B | 259 | 2.632 | 58.433 | 78.802 | 1.00 | 17.80 | B | C |
| ATOM | 1191 | CZ | TYR | B | 259 | 4.019 | 58.530 | 78.846 | 1.00 | 19.72 | B | C |
| ATOM | 1192 | OH | TYR | B | 259 | 4.644 | 59.138 | 79.909 | 1.00 | 17.71 | B | O |
| ATOM | 1193 | C | TYR | B | 259 | 2.629 | 58.557 | 74.036 | 1.00 | 11.43 | B | C |
| ATOM | 1194 | O | TYR | B | 259 | 2.546 | 59.751 | 74.311 | 1.00 | 11.27 | B | O |
| ATOM | 1195 | N | THR | B | 260 | 3.644 | 58.048 | 73.343 | 1.00 | 10.47 | B | N |
| ATOM | 1196 | CA | THR | B | 260 | 4.744 | 58.891 | 72.873 | 1.00 | 12.59 | B | C |
| ATOM | 1197 | CB | THR | B | 260 | 5.819 | 58.053 | 72.122 | 1.00 | 12.25 | B | C |
| ATOM | 1198 | OG1 | THR | B | 260 | 5.237 | 57.401 | 70.986 | 1.00 | 12.86 | B | O |
| ATOM | 1199 | CG2 | THR | B | 260 | 6.399 | 56.995 | 73.046 | 1.00 | 10.11 | 5 | C |
| ATOM | 1200 | C | THR | B | 260 | 4.253 | 60.027 | 71.973 | 1.00 | 11.44 | B | C |
| ATOM | 1201 | O | THR | B | 260 | 4.791 | 61.135 | 72.006 | 1.00 | 12.11 | B | O |
| ATOM | 1202 | N | HIS | B | 261 | 3.220 | 59.758 | 71.182 | 1.00 | 13.55 | B | N |
| ATOM | 1203 | CA | HIS | B | 261 | 2.662 | 60.775 | 70.299 | 1.00 | 15.20 | B | C |
| ATOM | 1204 | CB | HIS | B | 261 | 1.581 | 60.170 | 69.403 | 1.00 | 18.77 | B | C |
| ATOM | 1205 | CG | HIS | B | 261 | 1.001 | 61.140 | 68.419 | 1.00 | 21.23 | B | C |
| ATOM | 1206 | CD2 | HIS | B | 261 | 1.579 | 61.847 | 67.418 | 1.00 | 19.63 | B | C |
| ATOM | 1207 | ND1 | HIS | B | 261 | −0.337 | 61.478 | 68.406 | 1.00 | 21.93 | B | N |
| ATOM | 1208 | CE1 | HIS | B | 261 | −0.558 | 62.350 | 67.440 | 1.00 | 20.30 | B | C |
| ATOM | 1209 | NE2 | HIS | B | 261 | 0.587 | 62.590 | 66.826 | 1.00 | 22.42 | B | N |
| ATOM | 1210 | C | HIS | B | 261 | 2.060 | 61.904 | 71.131 | 1.00 | 16.10 | B | C |
| ATOM | 1211 | O | HIS | B | 261 | 2.221 | 63.081 | 70.807 | 1.00 | 17.24 | B | O |
| ATOM | 1212 | N | ARG | B | 262 | 1.366 | 61.536 | 72.204 | 1.00 | 16.90 | B | N |
| ATOM | 1213 | CA | ARG | B | 262 | 0.742 | 62.510 | 73.099 | 1.00 | 15.57 | B | C |
| ATOM | 1214 | CB | ARG | B | 262 | −0.159 | 61.788 | 74.099 | 1.00 | 17.94 | B | C |
| ATOM | 1215 | CG | ARG | B | 262 | −1.429 | 62.539 | 74.428 | 1.00 | 27.94 | B | C |
| ATOM | 1216 | CD | ARG | B | 262 | −2.221 | 61.847 | 75.526 | 1.00 | 32.90 | B | C |
| ATOM | 1217 | NE | ARG | B | 262 | −2.580 | 60.477 | 75.163 | 1.00 | 38.35 | B | N |
| ATOM | 1218 | CZ | ARG | B | 262 | −2.351 | 59.421 | 75.937 | 1.00 | 40.61 | B | C |
| ATOM | 1219 | NH1 | ARG | B | 262 | −1.764 | 59.577 | 77.122 | 1.00 | 39.66 | B | N |
| ATOM | 1220 | NH2 | ARG | B | 262 | −2.707 | 58.208 | 75.530 | 1.00 | 38.80 | B | N |
| ATOM | 1221 | C | ARG | B | 262 | 1.776 | 63.355 | 73.851 | 1.00 | 13.37 | B | C |
| ATOM | 1222 | O | ARG | B | 262 | 1.589 | 64.561 | 74.032 | 1.00 | 14.75 | B | O |
| ATOM | 1223 | N | ARG | B | 263 | 2.861 | 62.725 | 74.292 | 1.00 | 10.14 | B | N |
| ATOM | 1224 | CA | ARG | B | 263 | 3.910 | 63.438 | 75.016 | 1.00 | 9.92 | B | C |
| ATOM | 1225 | CB | ARG | B | 263 | 4.919 | 62.444 | 75.594 | 1.00 | 8.97 | B | C |
| ATOM | 1226 | CG | ARG | B | 263 | 4.318 | 61.379 | 76.513 | 1.00 | 8.75 | B | C |
| ATOM | 1227 | CD | ARG | B | 263 | 3.462 | 61.987 | 77.626 | 1.00 | 3.09 | B | C |
| ATOM | 1228 | NE | ARG | B | 263 | 4.095 | 63.157 | 78.222 | 1.00 | 6.36 | B | N |
| ATOM | 1229 | CZ | ARG | B | 263 | 3.432 | 64.116 | 78.861 | 1.00 | 8.04 | B | C |
| ATOM | 1230 | NH1 | ARG | B | 263 | 2.115 | 64.045 | 78.989 | 1.00 | 7.54 | B | N |
| ATOM | 1231 | NH2 | ARG | B | 263 | 4.084 | 65.159 | 79.362 | 1.00 | 9.21 | B | N |
| ATOM | 1232 | C | ARG | B | 263 | 4.625 | 64.436 | 74.110 | 1.00 | 12.58 | B | C |
| ATOM | 1233 | O | ARG | B | 263 | 4.976 | 65.542 | 74.538 | 1.00 | 15.19 | B | O |
| ATOM | 1234 | N | LEU | B | 264 | 4.840 | 64.043 | 72.856 | 1.00 | 12.12 | B | N |
| ATOM | 1235 | CA | LEU | B | 264 | 5.493 | 64.905 | 71.871 | 1.00 | 11.70 | B | C |
| ATOM | 1236 | CB | LEU | B | 264 | 5.760 | 64.120 | 70.581 | 1.00 | 7.85 | B | C |
| ATOM | 1237 | CG | LEU | B | 264 | 6.903 | 63.107 | 70.669 | 1.00 | 5.49 | B | C |
| ATOM | 1238 | CD1 | LEU | B | 264 | 6.800 | 62.110 | 69.533 | 1.00 | 2.21 | B | C |
| ATOM | 1239 | CD2 | LEU | B | 264 | 8.245 | 63.840 | 70.645 | 1.00 | 2.66 | B | C |
| ATOM | 1240 | C | LEU | B | 264 | 4.617 | 66.122 | 71.572 | 1.00 | 10.77 | B | C |
| ATOM | 1241 | O | LEU | B | 264 | 5.113 | 67.229 | 71.376 | 1.00 | 11.98 | B | O |
| ATOM | 1242 | N | LYS | B | 265 | 3.306 | 65.913 | 71.538 | 1.00 | 12.44 | B | N |
| ATOM | 1243 | CA | LYS | B | 265 | 2.380 | 67.007 | 71.285 | 1.00 | 13.18 | B | C |
| ATOM | 1244 | CB | LYS | B | 265 | 0.953 | 66.483 | 71.130 | 1.00 | 15.12 | B | C |
| ATOM | 1245 | CG | LYS | B | 265 | 0.524 | 66.234 | 69.695 | 1.00 | 18.96 | B | C |
| ATOM | 1246 | CD | LYS | B | 265 | −0.537 | 65.146 | 69.616 | 1.00 | 26.28 | B | C |
| ATOM | 1247 | CE | LYS | B | 265 | −1.942 | 65.703 | 69.820 | 1.00 | 28.25 | B | C |
| ATOM | 1248 | NZ | LYS | B | 265 | −2.781 | 64.818 | 70.684 | 1.00 | 33.02 | B | N |
| ATOM | 1249 | C | LYS | B | 265 | 2.449 | 67.942 | 72.474 | 1.00 | 13.45 | B | C |
| ATOM | 1250 | O | LYS | B | 265 | 2.375 | 69.160 | 72.321 | 1.00 | 18.31 | B | O |
| ATOM | 1251 | N | PHE | B | 266 | 2.601 | 67.372 | 73.666 | 1.00 | 14.15 | B | N |
| ATOM | 1252 | CA | PHE | B | 266 | 2.680 | 68.188 | 74.872 | 1.00 | 13.07 | B | C |
| ATOM | 1253 | CB | PHE | B | 266 | 2.614 | 67.324 | 76.134 | 1.00 | 12.46 | B | C |
| ATOM | 1254 | CG | PHE | B | 266 | 2.785 | 68.113 | 77.402 | 1.00 | 11.24 | B | C |
| ATOM | 1255 | CD1 | PHE | B | 266 | 1.701 | 68.768 | 77.976 | 1.00 | 10.85 | B | C |
| ATOM | 1256 | CD2 | PHE | B | 266 | 4.038 | 68.249 | 77.991 | 1.00 | 10.75 | B | C |
| ATOM | 1257 | CE1 | PHE | B | 266 | 1.860 | 69.554 | 79.116 | 1.00 | 10.74 | B | C |
| ATOM | 1258 | CE2 | PHE | B | 266 | 4.209 | 69.035 | 79.134 | 1.00 | 12.69 | B | C |
| ATOM | 1259 | CZ | PHE | B | 266 | 3.121 | 69.689 | 79.697 | 1.00 | 10.51 | B | C |
| ATOM | 1260 | C | PHE | B | 266 | 3.968 | 68.996 | 74.881 | 1.00 | 10.10 | B | C |
| ATOM | 1261 | O | PHE | B | 266 | 3.970 | 70.183 | 75.215 | 1.00 | 12.30 | B | O |
| ATOM | 1262 | N | LEU | B | 267 | 5.067 | 68.347 | 74.533 | 1.00 | 8.66 | B | N |
| ATOM | 1263 | CA | LEU | B | 267 | 6.353 | 69.027 | 74.490 | 1.00 | 9.70 | B | C |
| ATOM | 1264 | CB | LEU | B | 267 | 7.426 | 68.069 | 73.972 | 1.00 | 11.17 | B | C |
| ATOM | 1265 | CG | LEU | B | 267 | 8.426 | 67.440 | 74.951 | 1.00 | 12.44 | B | C |
| ATOM | 1266 | CD1 | LEU | B | 267 | 7.956 | 67.586 | 76.371 | 1.00 | 9.33 | B | C |
| ATOM | 1267 | CD2 | LEU | B | 267 | 8.612 | 65.979 | 74.606 | 1.00 | 11.59 | B | C |
| ATOM | 1268 | C | LEU | B | 267 | 6.251 | 70.239 | 73.570 | 1.00 | 10.66 | B | C |
| ATOM | 1269 | O | LEU | B | 267 | 6.797 | 71.305 | 73.862 | 1.00 | 13.00 | B | O |
| ATOM | 1270 | N | SER | B | 268 | 5.539 | 70.065 | 72.459 | 1.00 | 11.41 | B | N |
| ATOM | 1271 | CA | SER | B | 268 | 5.339 | 71.123 | 71.471 | 1.00 | 9.53 | B | C |
| ATOM | 1272 | CG | SER | B | 268 | 4.619 | 70.552 | 70.248 | 1.00 | 11.21 | B | C |
| ATOM | 1273 | OG | SER | B | 268 | 4.482 | 71.528 | 69.230 | 1.00 | 15.74 | B | O |
| ATOM | 1274 | C | SER | B | 268 | 4.532 | 72.288 | 72.037 | 1.00 | 8.91 | B | C |
| ATOM | 1275 | O | SER | B | 268 | 5.001 | 73.425 | 72.051 | 1.00 | 10.49 | B | O |
| ATOM | 1276 | N | SER | B | 269 | 3.319 | 72.005 | 72.504 | 1.00 | 7.05 | B | N |
| ATOM | 1277 | CA | SER | B | 269 | 2.458 | 73.042 | 73.069 | 1.00 | 8.84 | B | C |
| ATOM | 1278 | CB | SER | B | 269 | 1.113 | 72.445 | 73.493 | 1.00 | 7.64 | B | C |
| ATOM | 1279 | OG | SER | B | 269 | 0.348 | 72.046 | 72.375 | 1.00 | 9.83 | B | O |
| ATOM | 1280 | C | SER | B | 269 | 3.102 | 73.737 | 74.270 | 1.00 | 9.39 | B | C |
| ATOM | 1281 | O | SER | B | 269 | 2.967 | 74.946 | 74.438 | 1.00 | 8.83 | B | O |
| ATOM | 1282 | N | LYS | B | 270 | 3.790 | 72.974 | 75.112 | 1.00 | 9.70 | B | N |
| ATOM | 1283 | CA | LYS | B | 270 | 4.439 | 73.563 | 76.280 | 1.00 | 11.76 | B | C |
| ATOM | 1284 | CB | LYS | B | 270 | 5.179 | 72.496 | 77.100 | 1.00 | 11.69 | B | C |
| ATOM | 1285 | CG | LYS | B | 270 | 5.289 | 72.875 | 78.584 | 1.00 | 12.91 | B | C |
| ATOM | 1286 | CD | LYS | B | 270 | 6.377 | 72.112 | 79.311 | 1.00 | 9.89 | B | C |
| ATOM | 1287 | CE | LYS | B | 270 | 6.718 | 72.786 | 80.648 | 1.00 | 11.42 | B | C |
| ATOM | 1288 | NZ | LYS | B | 270 | 7.785 | 72.057 | 81.419 | 1.00 | 8.74 | B | N |
| ATOM | 1289 | C | LYS | B | 270 | 5.414 | 74.673 | 75.898 | 1.00 | 10.45 | B | C |
| ATOM | 1290 | O | LYS | B | 270 | 5.414 | 75.739 | 76.508 | 1.00 | 11.77 | B | O |
| ATOM | 1291 | N | PHE | B | 271 | 6.249 | 74.425 | 74.893 | 1.00 | 12.81 | B | N |
| ATOM | 1292 | CA | PHE | B | 271 | 7.215 | 75.433 | 74.449 | 1.00 | 12.96 | B | C |
| ATOM | 1293 | CB | PHE | B | 271 | 8.113 | 74.862 | 73.351 | 1.00 | 12.12 | B | C |
| ATOM | 1294 | CG | PHE | B | 271 | 9.221 | 75.789 | 72.932 | 1.00 | 12.04 | B | C |
| ATOM | 1295 | CD1 | PHE | B | 271 | 10.388 | 75.890 | 73.688 | 1.00 | 13.48 | B | C |
| ATOM | 1296 | CD2 | PHE | B | 271 | 9.094 | 76.579 | 71.789 | 1.00 | 9.18 | B | C |
| ATOM | 1297 | CE1 | PHE | B | 271 | 11.419 | 76.772 | 73.311 | 1.00 | 12.46 | B | C |
| ATOM | 1298 | CE2 | PHE | B | 271 | 10.115 | 77.458 | 71.408 | 1.00 | 9.90 | B | C |
| ATOM | 1299 | CZ | PHE | B | 271 | 11.279 | 77.553 | 72.172 | 1.00 | 10.20 | B | C |
| ATOM | 1300 | C | PHE | B | 271 | 6.510 | 76.683 | 73.927 | 1.00 | 13.37 | B | C |
| ATOM | 1301 | O | PHE | B | 271 | 6.950 | 77.807 | 74.170 | 1.00 | 12.01 | B | O |
| ATOM | 1302 | N | GLN | B | 272 | 5.410 | 76.483 | 73.209 | 1.00 | 16.80 | B | N |
| ATOM | 1303 | CA | GLN | B | 272 | 4.655 | 77.603 | 72.663 | 1.00 | 18.21 | B | C |
| ATOM | 1304 | CB | GLN | B | 272 | 3.452 | 77.092 | 71.880 | 1.00 | 18.60 | B | C |
| ATOM | 1305 | CG | GLN | B | 272 | 3.552 | 77.364 | 70.400 | 1.00 | 27.59 | B | C |
| ATOM | 1306 | CD | GLN | B | 272 | 3.691 | 76.097 | 69.589 | 1.00 | 32.97 | B | C |
| ATOM | 1307 | OE1 | GLN | B | 272 | 2.693 | 75.488 | 69.187 | 1.00 | 33.28 | B | O |
| ATOM | 1308 | NE2 | GLN | B | 272 | 4.934 | 75.688 | 69.339 | 1.00 | 34.78 | B | N |
| ATOM | 1309 | C | GLN | B | 272 | 4.190 | 78.541 | 73.769 | 1.00 | 16.03 | B | C |
| ATOM | 1310 | O | GLN | B | 272 | 4.261 | 79.766 | 73.634 | 1.00 | 16.19 | B | O |
| ATOM | 1311 | N | VAL | B | 273 | 3.712 | 77.967 | 74.865 | 1.00 | 13.58 | B | N |
| ATOM | 1312 | CA | VAL | B | 273 | 3.252 | 78.768 | 75.986 | 1.00 | 10.92 | B | C |
| ATOM | 1313 | CB | VAL | B | 273 | 2.438 | 77.917 | 76.985 | 1.00 | 11.84 | B | C |
| ATOM | 1314 | CG1 | VAL | B | 273 | 2.051 | 78.751 | 78.186 | 1.00 | 12.83 | B | C |
| ATOM | 1315 | CG2 | VAL | B | 273 | 1.187 | 77.378 | 76.308 | 1.00 | 11.13 | B | C |
| ATOM | 1316 | C | VAL | B | 273 | 4.448 | 79.386 | 76.702 | 1.00 | 11.29 | B | C |
| ATOM | 1317 | O | VAL | B | 273 | 4.398 | 80.540 | 77.131 | 1.00 | 12.66 | B | O |
| ATOM | 1318 | N | HIS | B | 274 | 5.528 | 78.626 | 76.831 | 1.00 | 11.81 | B | N |
| ATOM | 1319 | CA | HIS | B | 274 | 6.722 | 79.137 | 77.497 | 1.00 | 12.18 | B | C |
| ATOM | 1320 | CB | HIS | B | 274 | 7.814 | 78.067 | 77.542 | 1.00 | 9.06 | B | C |
| ATOM | 1321 | CG | HIS | B | 274 | 9.173 | 78.603 | 77.879 | 1.00 | 10.25 | B | C |
| ATOM | 1322 | CD2 | HIS | B | 274 | 10.318 | 78.649 | 77.157 | 1.00 | 12.41 | B | C |
| ATOM | 1323 | ND1 | HIS | B | 274 | 9.470 | 79.166 | 79.100 | 1.00 | 14.56 | B | N |
| ATOM | 1324 | CE1 | HIS | B | 274 | 10.740 | 79.535 | 79.120 | 1.00 | 13.05 | B | C |
| ATOM | 1325 | NE2 | HIS | B | 274 | 11.278 | 79.233 | 77.952 | 1.00 | 13.00 | B | N |
| ATOM | 1326 | C | HIS | B | 274 | 7.242 | 80.364 | 76.759 | 1.00 | 16.43 | B | C |
| ATOM | 1327 | O | HIS | B | 274 | 7.494 | 81.410 | 77.365 | 1.00 | 17.30 | B | O |
| ATOM | 1328 | N | GLN | B | 275 | 7.389 | 80.239 | 75.445 | 1.00 | 17.94 | B | N |
| ATOM | 1329 | CA | GLN | B | 275 | 7.893 | 81.341 | 74.636 | 1.00 | 22.05 | B | C |
| ATOM | 1330 | CB | GLN | B | 275 | 8.128 | 80.892 | 73.194 | 1.00 | 25.01 | B | C |
| ATOM | 1331 | CD | GLN | B | 275 | 9.544 | 81.165 | 72.709 | 1.00 | 37.20 | B | C |
| ATOM | 1332 | CD | GLN | B | 275 | 9.679 | 81.030 | 71.196 | 1.00 | 44.86 | B | C |
| ATOM | 1333 | OE1 | GLN | B | 275 | 8.683 | 81.107 | 70.456 | 1.00 | 47.03 | B | O |
| ATOM | 1334 | NE2 | GLN | B | 275 | 10.916 | 80.826 | 70.725 | 1.00 | 44.05 | B | N |
| ATOM | 1335 | C | GLN | B | 275 | 6.986 | 82.554 | 74.640 | 1.00 | 20.52 | B | C |
| ATOM | 1336 | O | GLN | B | 275 | 7.463 | 83.687 | 74.691 | 1.00 | 22.04 | B | O |
| ATOM | 1337 | N | MET | B | 276 | 5.680 | 82.335 | 74.587 | 1.00 | 17.61 | B | N |
| ATOM | 1338 | CA | MET | B | 276 | 4.776 | 83.464 | 74.575 | 1.00 | 19.13 | B | C |
| ATOM | 1339 | CB | MET | B | 276 | 3.380 | 83.012 | 74.139 | 1.00 | 20.26 | B | C |
| ATOM | 1340 | CG | MET | B | 276 | 2.507 | 82.457 | 75.231 | 1.00 | 23.09 | B | C |
| ATOM | 1341 | SD | MET | B | 276 | 0.876 | 82.020 | 74.554 | 1.00 | 27.74 | B | S |
| ATOM | 1342 | CE | MET | B | 276 | 1.283 | 80.629 | 73.501 | 1.00 | 19.77 | B | C |
| ATOM | 1343 | C | MET | B | 276 | 4.731 | 84.148 | 75.934 | 1.00 | 18.74 | B | C |
| ATOM | 1344 | O | MET | B | 276 | 4.466 | 85.345 | 76.026 | 1.00 | 19.22 | B | O |
| ATOM | 1345 | N | LEU | B | 277 | 5.012 | 83.393 | 76.988 | 1.00 | 16.62 | B | N |
| ATOM | 1346 | CA | LEU | B | 277 | 4.991 | 83.955 | 78.330 | 1.00 | 15.22 | B | C |
| ATOM | 1347 | CB | LEU | B | 277 | 4.558 | 82.882 | 79.329 | 1.00 | 12.66 | B | C |
| ATOM | 1348 | CG | LEU | B | 277 | 3.173 | 82.878 | 79.972 | 1.00 | 11.42 | B | C |
| ATOM | 1349 | CD1 | LEU | B | 277 | 2.127 | 83.521 | 79.072 | 1.00 | 14.42 | B | C |
| ATOM | 1350 | CD2 | LEU | B | 277 | 2.808 | 81.445 | 80.264 | 1.00 | 14.79 | B | C |
| ATOM | 1351 | C | LEU | B | 277 | 6.339 | 84.522 | 78.776 | 1.00 | 13.38 | B | C |
| ATOM | 1352 | O | LEU | B | 277 | 6.381 | 85.521 | 79.499 | 1.00 | 12.12 | B | O |
| ATOM | 1353 | N | ASN | B | 278 | 7.434 | 83.907 | 78.323 | 1.00 | 12.63 | B | N |
| ATOM | 1354 | CA | ASN | B | 278 | 8.769 | 84.312 | 78.765 | 1.00 | 13.78 | B | C |
| ATOM | 1355 | CB | ASN | B | 278 | 9.334 | 83.183 | 79.640 | 1.00 | 14.55 | B | C |
| ATOM | 1356 | CG | ASN | B | 278 | 8.416 | 82.842 | 80.812 | 1.00 | 14.74 | B | C |
| ATOM | 1357 | OD1 | ASN | B | 278 | 7.962 | 81.703 | 80.959 | 1.00 | 10.84 | B | O |
| ATOM | 1358 | ND2 | ASN | B | 278 | 8.130 | 83.843 | 81.646 | 1.00 | 15.29 | B | N |
| ATOM | 1359 | C | ASN | B | 278 | 9.853 | 84.761 | 77.777 | 1.00 | 14.62 | B | C |
| ATOM | 1360 | O | ASN | B | 278 | 10.977 | 85.073 | 78.191 | 1.00 | 13.91 | B | O |
| ATOM | 1361 | N | GLU | B | 279 | 9.542 | 84.815 | 76.487 | 1.00 | 16.67 | B | N |
| ATOM | 1362 | CA | GLU | B | 279 | 10.541 | 85.224 | 75.494 | 1.00 | 15.37 | B | C |
| ATOM | 1363 | CB | GLU | B | 279 | 9.927 | 85.233 | 74.096 | 1.00 | 15.33 | B | C |
| ATOM | 1364 | CG | GLU | B | 279 | 8.719 | 86.132 | 73.959 | 1.00 | 18.49 | B | C |
| ATOM | 1365 | CD | GLU | B | 279 | 8.209 | 86.196 | 72.545 | 1.00 | 21.18 | B | C |
| ATOM | 1366 | OE1 | GLU | B | 279 | 9.010 | 85.947 | 71.624 | 1.00 | 28.17 | B | O |
| ATOM | 1367 | OE2 | GLU | B | 279 | 7.012 | 86.493 | 72.347 | 1.00 | 24.76 | B | O |
| ATOM | 1368 | C | GLU | B | 279 | 11.169 | 86.585 | 75.780 | 1.00 | 13.95 | B | C |
| ATOM | 1369 | O | GLU | B | 279 | 12.357 | 86.774 | 75.557 | 1.00 | 15.65 | B | O |
| ATOM | 1370 | N | MET | B | 280 | 10.380 | 87.535 | 76.271 | 1.00 | 18.72 | B | N |
| ATOM | 1371 | CA | MET | B | 280 | 10.907 | 88.867 | 76.574 | 1.00 | 20.84 | B | C |
| ATOM | 1372 | CB | MET | B | 280 | 9.775 | 89.824 | 76.975 | 1.00 | 27.85 | B | C |
| ATOM | 1373 | CG | MET | B | 280 | 9.026 | 90.485 | 75.810 | 1.00 | 36.37 | B | C |
| ATOM | 1374 | SD | MET | B | 280 | 9.975 | 90.576 | 74.254 | 1.00 | 50.73 | B | S |
| ATOM | 1375 | CE | MET | B | 280 | 10.379 | 92.343 | 74.217 | 1.00 | 47.44 | B | C |
| ATOM | 1376 | C | MET | B | 280 | 11.902 | 88.753 | 77.716 | 1.00 | 18.42 | B | C |
| ATOM | 1377 | O | MET | B | 280 | 12.900 | 89.463 | 77.766 | 1.00 | 19.42 | B | O |
| ATOM | 1378 | N | ASP | B | 281 | 11.615 | 87.836 | 78.630 | 1.00 | 20.23 | B | N |
| ATOM | 1379 | CA | ASP | B | 281 | 12.466 | 87.597 | 79.786 | 1.00 | 19.83 | B | C |
| ATOM | 1380 | CB | ASP | B | 281 | 11.708 | 86.735 | 80.794 | 1.00 | 21.95 | B | C |
| ATOM | 1381 | CG | ASP | B | 281 | 10.565 | 87.490 | 81.431 | 1.00 | 23.88 | B | C |
| ATOM | 1382 | OD1 | ASP | B | 281 | 9.398 | 87.049 | 81.316 | 1.00 | 26.68 | B | O |
| ATOM | 1383 | OD2 | ASP | B | 281 | 10.848 | 88.544 | 82.036 | 1.00 | 26.34 | B | O |
| ATOM | 1384 | C | ASP | B | 281 | 13.785 | 86.947 | 79.392 | 1.00 | 17.73 | B | C |
| ATOM | 1385 | O | ASP | B | 281 | 14.830 | 87.262 | 79.961 | 1.00 | 18.84 | B | O |
| ATOM | 1386 | N | GLU | B | 282 | 13.740 | 86.040 | 78.422 | 1.00 | 15.69 | B | N |
| ATOM | 1387 | CA | GLU | B | 282 | 14.961 | 85.395 | 77.952 | 1.00 | 14.81 | B | C |
| ATOM | 1388 | CB | GLU | B | 282 | 14.612 | 84.242 | 77.012 | 1.00 | 13.80 | B | C |
| ATOM | 1389 | CG | GLU | B | 282 | 14.010 | 83.054 | 77.735 | 1.00 | 12.72 | B | C |
| ATOM | 1390 | CD | GLU | B | 282 | 13.633 | 81.933 | 76.800 | 1.00 | 14.94 | B | C |
| ATOM | 1391 | OE1 | GLU | B | 282 | 13.219 | 82.237 | 75.666 | 1.00 | 16.87 | B | O |
| ATOM | 1392 | OE2 | GLU | B | 282 | 13.749 | 80.748 | 77.191 | 1.00 | 16.57 | B | O |
| ATOM | 1393 | C | GLU | B | 282 | 15.827 | 86.440 | 77.238 | 1.00 | 13.19 | B | C |
| ATOM | 1394 | O | GLU | B | 282 | 17.042 | 86.469 | 77.411 | 1.00 | 12.81 | B | O |
| ATOM | 1395 | N | LEU | B | 283 | 15.195 | 87.311 | 76.456 | 1.00 | 11.76 | B | N |
| ATOM | 1396 | CA | LEU | B | 283 | 15.912 | 88.369 | 75.739 | 1.00 | 13.09 | B | C |
| ATOM | 1397 | CB | LEU | B | 283 | 14.926 | 89.224 | 74.929 | 1.00 | 11.08 | B | C |
| ATOM | 1398 | CG | LEU | B | 283 | 15.296 | 89.723 | 73.527 | 1.00 | 11.72 | B | C |
| ATOM | 1399 | CD1 | LEU | B | 283 | 14.610 | 91.052 | 73.272 | 1.00 | 6.82 | B | C |
| ATOM | 1400 | CD2 | LEU | B | 283 | 16.799 | 89.849 | 73.380 | 1.00 | 8.80 | B | C |
| ATOM | 1401 | C | LEU | B | 283 | 16.669 | 89.265 | 76.720 | 1.00 | 14.52 | B | C |
| ATOM | 1402 | O | LEU | B | 283 | 17.840 | 89.606 | 76.507 | 1.00 | 16.23 | B | O |
| ATOM | 1403 | N | LYS | B | 284 | 15.981 | 89.653 | 77.789 | 1.00 | 16.50 | B | N |
| ATOM | 1404 | CA | LYS | B | 284 | 16.555 | 90.503 | 78.828 | 1.00 | 16.73 | B | C |
| ATOM | 1405 | CB | LYS | B | 284 | 15.557 | 90.632 | 79.984 | 1.00 | 20.58 | B | C |
| ATOM | 1406 | CG | LYS | B | 284 | 15.915 | 91.666 | 81.034 | 1.00 | 24.51 | B | C |
| ATOM | 1407 | CD | LYS | B | 284 | 14.916 | 91.653 | 82.183 | 1.00 | 27.88 | B | C |
| ATOM | 1408 | CE | LYS | B | 284 | 15.278 | 92.684 | 83.251 | 1.00 | 32.23 | B | C |
| ATOM | 1409 | NZ | LYS | B | 284 | 14.085 | 93.106 | 84.052 | 1.00 | 38.40 | B | N |
| ATOM | 1410 | C | LYS | B | 284 | 17.884 | 89.931 | 79.337 | 1.00 | 15.36 | B | C |
| ATOM | 1411 | O | LYS | B | 284 | 18.862 | 90.660 | 79.511 | 1.00 | 14.50 | B | O |
| ATOM | 1412 | N | GLU | B | 285 | 17.925 | 88.624 | 79.572 | 1.00 | 14.06 | B | N |
| ATOM | 1413 | CA | GLU | B | 285 | 19.151 | 87.991 | 80.043 | 1.00 | 13.41 | B | C |
| ATOM | 1414 | CB | GLU | B | 285 | 18.960 | 86.481 | 80.180 | 1.00 | 13.12 | B | C |
| ATOM | 1415 | CG | GLU | B | 285 | 18.083 | 86.016 | 81.330 | 1.00 | 9.99 | B | C |
| ATOM | 1416 | CD | GLU | B | 285 | 18.369 | 84.572 | 81.702 | 1.00 | 13.86 | B | C |
| ATOM | 1417 | OE1 | GLU | B | 285 | 19.498 | 84.290 | 82.170 | 1.00 | 16.19 | B | O |
| ATOM | 1418 | OE2 | GLU | B | 285 | 17.478 | 83.716 | 81.520 | 1.00 | 13.88 | B | O |
| ATOM | 1419 | C | GLU | B | 285 | 20.292 | 88.250 | 79.055 | 1.00 | 17.45 | B | C |
| ATOM | 1420 | O | GLU | B | 285 | 21.401 | 88.641 | 79.454 | 1.00 | 17.06 | B | O |
| ATOM | 1421 | N | LEU | B | 286 | 20.017 | 88.034 | 77.765 | 1.00 | 18.37 | B | N |
| ATOM | 1422 | CA | LEU | B | 286 | 21.025 | 88.219 | 76.715 | 1.00 | 18.19 | B | C |
| ATOM | 1423 | CB | LEU | B | 286 | 20.496 | 87.724 | 75.361 | 1.00 | 17.32 | B | C |
| ATOM | 1424 | CG | LEU | B | 286 | 19.926 | 86.308 | 75.177 | 1.00 | 16.02 | B | C |
| ATOM | 1425 | CD1 | LEU | B | 286 | 20.389 | 85.775 | 73.841 | 1.00 | 15.88 | B | C |
| ATOM | 1426 | CD2 | LEU | B | 286 | 20.356 | 85.380 | 76.283 | 1.00 | 12.75 | B | C |
| ATOM | 1427 | C | LEU | B | 286 | 21.464 | 89.670 | 76.580 | 1.00 | 18.07 | B | C |
| ATOM | 1428 | O | LEU | B | 286 | 22.643 | 89.950 | 76.370 | 1.00 | 18.90 | B | O |
| ATOM | 1429 | N | LYS | B | 287 | 20.511 | 90.590 | 76.683 | 1.00 | 19.92 | B | N |
| ATOM | 1430 | CA | LYS | B | 287 | 20.822 | 92.007 | 76.586 | 1.00 | 19.78 | B | C |
| ATOM | 1431 | CB | LYS | B | 287 | 19.537 | 92.829 | 76.602 | 1.00 | 18.42 | B | C |
| ATOM | 1432 | CG | LYS | B | 287 | 18.909 | 93.029 | 75.241 | 1.00 | 20.20 | B | C |
| ATOM | 1433 | CD | LYS | B | 287 | 17.401 | 93.155 | 75.373 | 1.00 | 23.52 | B | C |
| ATOM | 1434 | CE | LYS | B | 287 | 16.912 | 94.529 | 74.950 | 1.00 | 25.49 | B | C |
| ATOM | 1435 | NZ | LYS | B | 287 | 15.436 | 94.532 | 74.734 | 1.00 | 27.98 | B | N |
| ATOM | 1436 | C | LYS | B | 287 | 21.722 | 92.451 | 77.742 | 1.00 | 20.85 | B | C |
| ATOM | 1437 | O | LYS | B | 287 | 22.584 | 93.311 | 77.571 | 1.00 | 20.97 | B | O |
| ATOM | 1438 | N | ASN | B | 288 | 21.518 | 91.867 | 78.918 | 1.00 | 22.89 | B | N |
| ATOM | 1439 | CA | ASN | B | 288 | 22.323 | 92.219 | 80.086 | 1.00 | 25.69 | B | C |
| ATOM | 1440 | CB | ASN | B | 288 | 21.510 | 92.046 | 81.371 | 1.00 | 25.09 | B | C |
| ATOM | 1441 | CG | ASN | B | 288 | 20.378 | 93.048 | 81.480 | 1.00 | 25.66 | B | C |
| ATOM | 1442 | OD1 | ASN | B | 288 | 20.522 | 94.216 | 81.112 | 1.00 | 21.24 | B | O |
| ATOM | 1443 | ND2 | ASN | B | 288 | 19.242 | 92.593 | 81.986 | 1.00 | 26.07 | B | N |
| ATOM | 1444 | C | ASN | B | 288 | 23.605 | 91.399 | 80.182 | 1.00 | 25.94 | B | C |
| ATOM | 1445 | O | ASN | B | 288 | 24.265 | 91.381 | 81.222 | 1.00 | 24.91 | B | O |
| ATOM | 1446 | N | ASN | B | 289 | 23.943 | 90.715 | 79.093 | 1.00 | 25.44 | B | N |
| ATOM | 1447 | CA | ASN | B | 289 | 25.159 | 89.915 | 79.028 | 1.00 | 25.69 | B | C |
| ATOM | 1448 | CB | ASN | B | 289 | 24.832 | 88.521 | 78.483 | 1.00 | 22.21 | B | C |
| ATOM | 1449 | CG | ASN | B | 289 | 26.020 | 87.584 | 78.510 | 1.00 | 17.90 | B | C |
| ATOM | 1450 | OD1 | ASN | B | 289 | 26.888 | 87.680 | 79.374 | 1.00 | 20.98 | B | O |
| ATOM | 1451 | ND2 | ASN | B | 289 | 26.063 | 86.669 | 77.558 | 1.00 | 13.85 | B | N |
| ATOM | 1452 | C | ASN | B | 289 | 26.071 | 90.681 | 78.074 | 1.00 | 27.90 | B | C |
| ATOM | 1453 | O | ASN | B | 289 | 26.026 | 90.473 | 76.863 | 1.00 | 32.22 | B | O |
| ATOM | 1454 | N | PRO | B | 290 | 26.900 | 91.597 | 78.613 | 1.00 | 28.45 | B | N |
| ATOM | 1455 | CD | PRO | B | 290 | 27.007 | 91.899 | 80.050 | 1.00 | 25.62 | B | C |
| ATOM | 1456 | CA | PRO | B | 290 | 27.826 | 92.416 | 77.821 | 1.00 | 28.42 | B | C |
| ATOM | 1457 | CB | PRO | B | 290 | 28.258 | 93.503 | 78.797 | 1.00 | 25.40 | B | C |
| ATOM | 1458 | CG | PRO | B | 290 | 28.170 | 92.847 | 80.115 | 1.00 | 26.22 | B | C |
| ATOM | 1459 | C | PRO | B | 290 | 29.016 | 91.668 | 77.241 | 1.00 | 29.55 | B | C |
| ATOM | 1460 | O | PRO | B | 290 | 29.760 | 92.199 | 76.416 | 1.00 | 29.25 | B | O |
| ATOM | 1461 | N | HIS | B | 291 | 29.194 | 90.429 | 77.667 | 1.00 | 31.53 | B | N |
| ATOM | 1462 | CA | HIS | B | 291 | 30.312 | 89.637 | 77.177 | 1.00 | 37.96 | B | C |
| ATOM | 1463 | CB | HIS | B | 291 | 30.626 | 88.507 | 78.165 | 1.00 | 42.13 | B | C |
| ATOM | 1464 | CG | HIS | B | 291 | 30.812 | 88.973 | 79.576 | 1.00 | 48.96 | B | C |
| ATOM | 1465 | CD2 | HIS | B | 291 | 31.934 | 89.237 | 80.288 | 1.00 | 48.72 | B | C |
| ATOM | 1466 | ND1 | HIS | B | 291 | 29.752 | 89.227 | 80.422 | 1.00 | 51.30 | B | N |
| ATOM | 1467 | CE1 | HIS | B | 291 | 30.215 | 89.626 | 81.595 | 1.00 | 51.69 | B | C |
| ATOM | 1468 | NE2 | HIS | B | 291 | 31.536 | 89.640 | 81.539 | 1.00 | 51.08 | B | N |
| ATOM | 1469 | C | HIS | B | 291 | 30.067 | 89.029 | 75.798 | 1.00 | 37.68 | B | C |
| ATOM | 1470 | O | HIS | B | 291 | 31.013 | 88.766 | 75.057 | 1.00 | 38.20 | B | O |
| ATOM | 1471 | N | ARG | B | 292 | 28.804 | 88.832 | 75.436 | 1.00 | 32.50 | B | N |
| ATOM | 1472 | CA | ARG | B | 292 | 28.525 | 88.184 | 74.174 | 1.00 | 26.06 | B | C |
| ATOM | 1473 | CB | ARG | B | 292 | 28.582 | 86.673 | 74.399 | 1.00 | 23.93 | B | C |
| ATOM | 1474 | CG | ARG | B | 292 | 29.757 | 85.996 | 73.762 | 1.00 | 24.17 | B | C |
| ATOM | 1475 | CD | ARG | B | 292 | 30.198 | 84.826 | 74.571 | 1.00 | 24.14 | B | C |
| ATOM | 1476 | NE | ARG | B | 292 | 31.458 | 85.100 | 75.253 | 1.00 | 27.92 | B | N |
| ATOM | 1477 | CZ | ARG | B | 292 | 32.647 | 85.130 | 74.656 | 1.00 | 25.53 | B | C |
| ATOM | 1478 | NH1 | ARG | B | 292 | 32.762 | 84.905 | 73.353 | 1.00 | 28.27 | B | N |
| ATOM | 1479 | NH2 | ARG | B | 292 | 33.731 | 85.375 | 75.370 | 1.00 | 26.05 | B | N |
| ATOM | 1480 | C | ARG | B | 292 | 27.222 | 88.502 | 73.465 | 1.00 | 25.76 | B | C |
| ATOM | 1481 | O | ARG | B | 292 | 26.274 | 89.056 | 74.045 | 1.00 | 26.44 | B | O |
| ATOM | 1482 | N | ASP | B | 293 | 27.213 | 88.133 | 72.183 | 1.00 | 23.24 | B | N |
| ATOM | 1483 | CA | ASP | B | 293 | 26.054 | 88.232 | 71.296 | 1.00 | 21.84 | B | C |
| ATOM | 1484 | CB | ASP | B | 293 | 25.969 | 89.588 | 70.564 | 1.00 | 19.78 | B | C |
| ATOM | 1485 | CG | ASP | B | 293 | 27.143 | 89.863 | 69.661 | 1.00 | 21.34 | B | C |
| ATOM | 1486 | OD1 | ASP | B | 293 | 27.477 | 91.057 | 69.503 | 1.00 | 20.30 | B | O |
| ATOM | 1487 | OD2 | ASP | B | 293 | 27.725 | 88.907 | 69.105 | 1.00 | 23.13 | B | O |
| ATOM | 1488 | C | ASP | B | 293 | 26.237 | 87.060 | 70.332 | 1.00 | 19.56 | B | C |
| ATOM | 1489 | O | ASP | B | 293 | 27.258 | 86.380 | 70.385 | 1.00 | 16.85 | B | O |
| ATOM | 1490 | N | PHE | B | 294 | 25.259 | 86.793 | 69.476 | 1.00 | 20.48 | B | N |
| ATOM | 1491 | CA | PHE | B | 294 | 25.380 | 85.660 | 68.566 | 1.00 | 20.06 | B | C |
| ATOM | 1492 | CB | PHE | B | 294 | 24.208 | 85.626 | 67.584 | 1.00 | 21.07 | B | C |
| ATOM | 1493 | CG | PHE | B | 294 | 24.296 | 84.503 | 66.574 | 1.00 | 21.85 | B | C |
| ATOM | 1494 | CD1 | PHE | B | 294 | 23.974 | 83.197 | 66.935 | 1.00 | 19.34 | B | C |
| ATOM | 1495 | CD2 | PHE | B | 294 | 24.725 | 84.747 | 65.272 | 1.00 | 20.37 | B | C |
| ATOM | 1496 | CE1 | PHE | B | 294 | 24.080 | 82.150 | 66.017 | 1.00 | 17.36 | B | C |
| ATOM | 1497 | CE2 | PHE | B | 294 | 24.834 | 83.704 | 64.350 | 1.00 | 19.46 | B | C |
| ATOM | 1498 | CZ | PHE | B | 294 | 24.511 | 82.406 | 64.727 | 1.00 | 16.66 | B | C |
| ATOM | 1499 | C | PHE | B | 294 | 26.679 | 85.625 | 67.769 | 1.00 | 19.42 | B | C |
| ATOM | 1500 | O | PHE | B | 294 | 27.235 | 84.557 | 67.527 | 1.00 | 19.19 | B | O |
| ATOM | 1501 | N | TYR | B | 295 | 27.168 | 86.792 | 67.374 | 1.00 | 19.10 | B | N |
| ATOM | 1502 | CA | TYR | B | 295 | 28.372 | 86.864 | 66.566 | 1.00 | 16.76 | B | C |
| ATOM | 1503 | CB | TYR | B | 295 | 28.472 | 88.252 | 65.950 | 1.00 | 16.34 | B | C |
| ATOM | 1504 | CG | TYR | B | 295 | 27.302 | 88.505 | 65.033 | 1.00 | 18.58 | B | C |
| ATOM | 1505 | CD1 | TYR | B | 295 | 27.270 | 87.961 | 63.753 | 1.00 | 17.07 | B | C |
| ATOM | 1506 | CE1 | TYR | B | 295 | 26.165 | 88.137 | 62.925 | 1.00 | 21.48 | B | C |
| ATOM | 1507 | CD2 | TYR | B | 295 | 26.195 | 89.235 | 65.468 | 1.00 | 20.52 | B | C |
| ATOM | 1508 | CE2 | TYR | B | 295 | 25.079 | 89.416 | 64.644 | 1.00 | 21.68 | B | C |
| ATOM | 1509 | CZ | TYR | B | 295 | 25.075 | 88.864 | 63.373 | 1.00 | 23.17 | B | C |
| ATOM | 1510 | OH | TYR | B | 295 | 23.995 | 89.053 | 62.540 | 1.00 | 25.68 | B | O |
| ATOM | 1511 | C | TYR | B | 295 | 29.691 | 86.449 | 67.183 | 1.00 | 17.32 | B | C |
| ATOM | 1512 | O | TYR | B | 295 | 30.636 | 86.170 | 66.455 | 1.00 | 22.03 | B | O |
| ATOM | 1513 | N | ASN | B | 296 | 29.797 | 86.411 | 68.503 | 1.00 | 16.63 | B | N |
| ATOM | 1514 | CA | ASN | B | 296 | 31.058 | 85.958 | 69.064 | 1.00 | 16.22 | B | C |
| ATOM | 1515 | CB | ASN | B | 296 | 31.848 | 87.102 | 69.734 | 1.00 | 18.02 | B | C |
| ATOM | 1516 | CG | ASN | B | 296 | 31.189 | 87.660 | 70.969 | 1.00 | 16.76 | B | C |
| ATOM | 1517 | OD1 | ASN | B | 296 | 31.814 | 88.422 | 71.699 | 1.00 | 17.69 | B | O |
| ATOM | 1518 | ND2 | ASN | B | 296 | 29.932 | 87.302 | 71.209 | 1.00 | 18.65 | B | N |
| ATOM | 1519 | C | ASN | B | 296 | 30.898 | 84.753 | 69.968 | 1.00 | 15.83 | B | C |
| ATOM | 1520 | O | ASN | B | 296 | 31.633 | 84.563 | 70.932 | 1.00 | 16.82 | B | O |
| ATOM | 1521 | N | CYS | B | 297 | 29.911 | 83.936 | 69.608 | 1.00 | 19.31 | B | N |
| ATOM | 1522 | CA | CYS | B | 297 | 29.605 | 82.661 | 70.262 | 1.00 | 19.52 | B | C |
| ATOM | 1523 | CB | CYS | B | 297 | 28.098 | 82.385 | 70.264 | 1.00 | 21.11 | B | C |
| ATOM | 1524 | SG | CYS | B | 297 | 27.176 | 83.132 | 71.604 | 1.00 | 29.34 | B | S |
| ATOM | 1525 | C | CYS | B | 297 | 30.244 | 81.685 | 69.281 | 1.00 | 17.71 | B | C |
| ATOM | 1526 | O | CYS | B | 297 | 30.289 | 81.966 | 68.082 | 1.00 | 18.19 | B | O |
| ATOM | 1527 | N | ARG | B | 298 | 30.735 | 80.554 | 69.756 | 1.00 | 16.20 | B | N |
| ATOM | 1528 | CA | ARG | B | 298 | 31.332 | 79.600 | 68.840 | 1.00 | 16.19 | B | C |
| ATOM | 1529 | CB | ARG | B | 298 | 32.280 | 78.673 | 69.585 | 1.00 | 16.69 | B | C |
| ATOM | 1530 | CG | ARG | B | 298 | 33.717 | 79.147 | 69.573 | 1.00 | 17.33 | B | C |
| ATOM | 1531 | CD | ARG | B | 298 | 33.884 | 80.393 | 70.412 | 1.00 | 16.39 | B | C |
| ATOM | 1532 | NE | ARG | B | 298 | 35.276 | 80.833 | 70.430 | 1.00 | 21.70 | B | N |
| ATOM | 1533 | CZ | ARG | B | 298 | 35.763 | 81.719 | 71.292 | 1.00 | 23.02 | B | C |
| ATOM | 1534 | NH1 | ARG | B | 298 | 34.968 | 82.259 | 72.206 | 1.00 | 24.09 | B | N |
| ATOM | 1535 | NH2 | ARG | B | 298 | 37.042 | 82.070 | 71.240 | 1.00 | 25.73 | B | N |
| ATOM | 1536 | C | ARG | B | 298 | 30.239 | 78.786 | 68.162 | 1.00 | 18.26 | B | C |
| ATOM | 1537 | O | ARG | B | 298 | 29.267 | 78.379 | 68.803 | 1.00 | 17.59 | B | O |
| ATOM | 1538 | N | LYS | B | 299 | 30.390 | 78.575 | 66.857 | 1.00 | 20.80 | B | N |
| ATOM | 1539 | CA | LYS | B | 299 | 29.431 | 77.792 | 66.072 | 1.00 | 19.65 | B | C |
| ATOM | 1540 | CB | LYS | B | 299 | 28.760 | 78.669 | 65.019 | 1.00 | 16.21 | B | C |
| ATOM | 1541 | CG | LYS | B | 299 | 27.384 | 79.181 | 65.415 | 1.00 | 20.18 | B | C |
| ATOM | 1542 | CD | LYS | B | 299 | 27.431 | 80.607 | 65.960 | 1.00 | 18.23 | B | C |
| ATOM | 1543 | CE | LYS | B | 299 | 28.442 | 81.459 | 65.216 | 1.00 | 16.87 | B | C |
| ATOM | 1544 | NZ | LYS | B | 299 | 28.685 | 82.758 | 65.894 | 1.00 | 16.78 | B | N |
| ATOM | 1545 | C | LYS | B | 299 | 30.220 | 76.690 | 65.382 | 1.00 | 18.55 | B | C |
| ATOM | 1546 | O | LYS | B | 299 | 31.279 | 76.957 | 64.817 | 1.00 | 21.82 | B | O |
| ATOM | 1547 | N | VAL | B | 300 | 29.727 | 75.457 | 65.428 | 1.00 | 15.88 | B | N |
| ATOM | 1548 | CA | VAL | B | 300 | 30.440 | 74.356 | 64.795 | 1.00 | 14.92 | B | C |
| ATOM | 1549 | CB | VAL | B | 300 | 30.856 | 73.304 | 65.840 | 1.00 | 13.49 | B | C |
| ATOM | 1550 | CG1 | VAL | B | 300 | 31.703 | 72.232 | 65.194 | 1.00 | 7.75 | B | C |
| ATOM | 1551 | CG2 | VAL | B | 300 | 31.629 | 73.975 | 66.963 | 1.00 | 11.21 | B | C |
| ATOM | 1552 | C | VAL | B | 300 | 29.636 | 73.664 | 63.690 | 1.00 | 17.05 | B | C |
| ATOM | 1553 | O | VAL | B | 300 | 28.453 | 73.345 | 63.874 | 1.00 | 17.74 | B | O |
| ATOM | 1554 | N | ASP | B | 301 | 30.277 | 73.460 | 62.537 | 1.00 | 13.69 | B | N |
| ATOM | 1555 | CA | ASP | B | 301 | 29.641 | 72.784 | 61.409 | 1.00 | 12.39 | B | C |
| ATOM | 1556 | CB | ASP | B | 301 | 30.324 | 73.153 | 60.088 | 1.00 | 12.61 | B | C |
| ATOM | 1557 | CG | ASP | B | 301 | 29.450 | 72.871 | 58.880 | 1.00 | 13.19 | B | C |
| ATOM | 1558 | OD1 | ASP | B | 301 | 29.746 | 73.410 | 57.797 | 1.00 | 14.87 | B | O |
| ATOM | 1559 | OD2 | ASP | B | 301 | 28.466 | 72.109 | 59.008 | 1.00 | 11.93 | B | O |
| ATOM | 1560 | C | ASP | B | 301 | 29.846 | 71.315 | 61.706 | 1.00 | 12.40 | B | C |
| ATOM | 1561 | O | ASP | B | 301 | 30.869 | 70.723 | 61.364 | 1.00 | 10.40 | B | O |
| ATOM | 1562 | N | THR | B | 302 | 28.854 | 70.729 | 62.353 | 1.00 | 14.86 | B | N |
| ATOM | 1563 | CA | THR | B | 302 | 28.929 | 69.341 | 62.771 | 1.00 | 14.86 | B | C |
| ATOM | 1564 | CB | THR | B | 302 | 27.905 | 69.109 | 63.884 | 1.00 | 12.96 | B | C |
| ATOM | 1565 | OG1 | THR | B | 302 | 26.698 | 69.818 | 63.565 | 1.00 | 12.90 | B | O |
| ATOM | 1566 | CG2 | THR | B | 302 | 28.450 | 69.633 | 65.214 | 1.00 | 8.04 | B | C |
| ATOM | 1567 | C | THR | B | 302 | 28.747 | 68.288 | 61.684 | 1.00 | 18.07 | B | C |
| ATOM | 1568 | O | THR | B | 302 | 28.908 | 67.094 | 61.939 | 1.00 | 19.87 | B | O |
| ATOM | 1569 | N | HIS | B | 303 | 28.437 | 68.716 | 60.468 | 1.00 | 19.07 | B | N |
| ATOM | 1570 | CA | HIS | B | 303 | 28.203 | 67.762 | 59.393 | 1.00 | 17.69 | B | C |
| ATOM | 1571 | CB | HIS | B | 303 | 26.727 | 67.372 | 59.384 | 1.00 | 18.85 | B | C |
| ATOM | 1572 | CG | HIS | B | 303 | 26.270 | 66.717 | 58.119 | 1.00 | 19.10 | B | C |
| ATOM | 1573 | CD2 | HIS | B | 303 | 26.859 | 65.781 | 57.339 | 1.00 | 18.80 | B | C |
| ATOM | 1574 | ND1 | HIS | B | 303 | 25.045 | 66.979 | 57.549 | 1.00 | 17.44 | B | N |
| ATOM | 1575 | CE1 | HIS | B | 303 | 24.893 | 66.233 | 56.473 | 1.00 | 18.05 | B | C |
| ATOM | 1576 | NE2 | HIS | B | 303 | 25.982 | 65.495 | 56.322 | 1.00 | 19.64 | B | N |
| ATOM | 1577 | C | HIS | B | 303 | 28.601 | 68.374 | 58.066 | 1.00 | 18.18 | B | C |
| ATOM | 1578 | O | HIS | B | 303 | 27.806 | 69.068 | 57.433 | 1.00 | 15.27 | B | O |
| ATOM | 1579 | N | ILE | B | 304 | 29.838 | 68.100 | 57.658 | 1.00 | 16.44 | B | N |
| ATOM | 1580 | CA | ILE | B | 304 | 30.384 | 68.633 | 56.422 | 1.00 | 15.89 | B | C |
| ATOM | 1581 | CB | ILE | B | 304 | 31.055 | 69.991 | 56.695 | 1.00 | 13.57 | B | C |
| ATOM | 1582 | CG2 | ILE | B | 304 | 31.971 | 69.871 | 57.886 | 1.00 | 13.63 | B | C |
| ATOM | 1583 | CG1 | ILE | B | 304 | 31.827 | 70.471 | 55.473 | 1.00 | 13.59 | B | C |
| ATOM | 1584 | CD1 | ILE | B | 304 | 31.917 | 71.988 | 55.373 | 1.00 | 13.87 | B | C |
| ATOM | 1585 | C | ILE | B | 304 | 31.395 | 67.673 | 55.808 | 1.00 | 14.88 | B | C |
| ATOM | 1586 | O | ILE | B | 304 | 32.244 | 67.125 | 56.507 | 1.00 | 16.39 | B | O |
| ATOM | 1587 | N | HIS | B | 305 | 31.298 | 67.477 | 54.495 | 1.00 | 15.67 | B | N |
| ATOM | 1588 | CA | HIS | B | 305 | 32.203 | 66.583 | 53.769 | 1.00 | 13.50 | B | C |
| ATOM | 1589 | CB | HIS | B | 305 | 31.427 | 65.833 | 52.690 | 1.00 | 7.84 | B | C |
| ATOM | 1590 | CG | HIS | B | 305 | 30.225 | 65.111 | 53.209 | 1.00 | 7.18 | B | C |
| ATOM | 1591 | CD2 | HIS | B | 305 | 28.970 | 65.547 | 53.483 | 1.00 | 9.25 | B | C |
| ATOM | 1592 | ND1 | HIS | B | 305 | 30.233 | 63.764 | 53.500 | 1.00 | 8.53 | B | N |
| ATOM | 1593 | CE1 | HIS | B | 305 | 29.035 | 63.398 | 53.925 | 1.00 | 8.43 | B | C |
| ATOM | 1594 | NE2 | HIS | B | 305 | 28.252 | 64.462 | 53.925 | 1.00 | 7.29 | B | N |
| ATOM | 1595 | C | HIS | B | 305 | 33.360 | 67.370 | 53.150 | 1.00 | 13.31 | B | C |
| ATOM | 1596 | O | HIS | B | 305 | 33.148 | 68.343 | 52.435 | 1.00 | 12.71 | B | O |
| ATOM | 1597 | N | ALA | B | 306 | 34.582 | 66.933 | 53.438 | 1.00 | 14.02 | B | N |
| ATOM | 1598 | CA | ALA | B | 306 | 35.791 | 67.591 | 52.954 | 1.00 | 14.78 | B | C |
| ATOM | 1599 | CB | ALA | B | 306 | 37.009 | 66.743 | 53.293 | 1.00 | 13.18 | B | C |
| ATOM | 1600 | C | ALA | B | 306 | 35.785 | 67.922 | 51.464 | 1.00 | 16.87 | B | C |
| ATOM | 1601 | O | ALA | B | 306 | 36.169 | 69.024 | 51.068 | 1.00 | 18.30 | B | O |
| ATOM | 1602 | N | ALA | B | 307 | 35.347 | 66.973 | 50.643 | 1.00 | 16.37 | B | N |
| ATOM | 1603 | CA | ALA | B | 307 | 35.312 | 67.161 | 49.196 | 1.00 | 13.93 | B | C |
| ATOM | 1604 | CB | ALA | B | 307 | 34.840 | 65.890 | 48.524 | 1.00 | 8.59 | B | C |
| ATOM | 1605 | C | ALA | B | 307 | 34.439 | 68.327 | 48.754 | 1.00 | 16.21 | B | C |
| ATOM | 1606 | O | ALA | B | 307 | 34.507 | 68.743 | 47.601 | 1.00 | 18.09 | B | O |
| ATOM | 1607 | N | ALA | B | 308 | 33.626 | 68.861 | 49.660 | 1.00 | 17.07 | B | N |
| ATOM | 1608 | CA | ALA | B | 308 | 32.743 | 69.969 | 49.315 | 1.00 | 13.74 | B | C |
| ATOM | 1609 | CB | ALA | B | 308 | 31.331 | 69.467 | 49.182 | 1.00 | 11.48 | B | C |
| ATOM | 1610 | C | ALA | B | 308 | 32.790 | 71.101 | 50.325 | 1.00 | 15.63 | B | C |
| ATOM | 1611 | O | ALA | B | 308 | 31.901 | 71.952 | 50.349 | 1.00 | 16.73 | B | O |
| ATOM | 1612 | N | CYS | B | 309 | 33.840 | 71.135 | 51.139 | 1.00 | 17.84 | B | N |
| ATOM | 1613 | CA | CYS | B | 309 | 33.961 | 72.167 | 52.165 | 1.00 | 20.42 | B | C |
| ATOM | 1614 | CB | CYS | B | 309 | 34.967 | 71.732 | 53.242 | 1.00 | 21.66 | B | C |
| ATOM | 1615 | SG | CYS | B | 309 | 36.695 | 71.627 | 52.718 | 1.00 | 26.17 | B | S |
| ATOM | 1616 | C | CYS | B | 309 | 34.318 | 73.558 | 51.665 | 1.00 | 18.92 | B | C |
| ATOM | 1617 | O | CYS | B | 309 | 34.314 | 74.518 | 52.435 | 1.00 | 19.80 | B | O |
| ATOM | 1618 | N | MET | B | 310 | 34.621 | 73.682 | 50.379 | 1.00 | 21.88 | B | N |
| ATOM | 1619 | CA | MET | B | 310 | 34.974 | 74.990 | 49.817 | 1.00 | 20.12 | B | C |
| ATOM | 1620 | CB | MET | B | 310 | 36.241 | 74.868 | 48.957 | 1.00 | 16.92 | B | C |
| ATOM | 1621 | CG | MET | B | 310 | 36.023 | 74.282 | 47.575 | 1.00 | 9.48 | B | C |
| ATOM | 1622 | SD | MET | B | 310 | 35.491 | 72.582 | 47.620 | 1.00 | 13.39 | B | S |
| ATOM | 1623 | CE | MET | B | 310 | 36.954 | 71.745 | 48.181 | 1.00 | 7.12 | B | C |
| ATOM | 1624 | C | MET | B | 310 | 33.825 | 75.579 | 48.991 | 1.00 | 20.54 | B | C |
| ATOM | 1625 | O | MET | B | 310 | 32.961 | 74.847 | 48.502 | 1.00 | 18.14 | B | O |
| ATOM | 1626 | N | ASN | B | 311 | 33.798 | 76.903 | 48.856 | 1.00 | 23.04 | B | N |
| ATOM | 1627 | CA | ASN | B | 311 | 32.750 | 77.533 | 48.060 | 1.00 | 24.28 | B | C |
| ATOM | 1628 | CB | ASN | B | 311 | 32.668 | 79.047 | 48.304 | 1.00 | 28.15 | B | C |
| ATOM | 1629 | CG | ASN | B | 311 | 31.476 | 79.687 | 47.576 | 1.00 | 38.23 | B | C |
| ATOM | 1630 | OD1 | ASN | B | 311 | 30.325 | 79.225 | 47.704 | 1.00 | 44.08 | B | O |
| ATOM | 1631 | ND2 | ASN | B | 311 | 31.742 | 80.742 | 46.805 | 1.00 | 37.35 | B | N |
| ATOM | 1632 | C | ASN | B | 311 | 33.073 | 77.283 | 46.599 | 1.00 | 21.63 | B | C |
| ATOM | 1633 | O | ASN | B | 311 | 34.233 | 77.121 | 46.232 | 1.00 | 18.58 | B | O |
| ATOM | 1634 | N | GLN | B | 312 | 32.045 | 77.249 | 45.763 | 1.00 | 22.71 | B | N |
| ATOM | 1635 | CA | GLN | B | 312 | 32.260 | 77.012 | 44.350 | 1.00 | 21.89 | B | C |
| ATOM | 1636 | CB | GLN | B | 312 | 30.925 | 76.905 | 43.631 | 1.00 | 18.45 | B | C |
| ATOM | 1637 | CG | GLN | B | 312 | 30.118 | 78.169 | 43.633 | 1.00 | 20.26 | B | C |
| ATOM | 1638 | CD | GLN | B | 312 | 28.860 | 78.026 | 42.808 | 1.00 | 18.15 | B | C |
| ATOM | 1639 | OE1 | GLN | B | 312 | 28.775 | 77.154 | 41.940 | 1.00 | 20.94 | B | O |
| ATOM | 1640 | NE2 | GLN | B | 312 | 27.870 | 78.879 | 43.074 | 1.00 | 17.81 | B | N |
| ATOM | 1641 | C | GLN | B | 312 | 33.120 | 78.112 | 43.728 | 1.00 | 22.65 | B | C |
| ATOM | 1642 | O | GLN | B | 312 | 33.876 | 77.855 | 42.792 | 1.00 | 24.64 | B | O |
| ATOM | 1643 | N | LYS | B | 313 | 33.019 | 79.330 | 44.251 | 1.00 | 21.48 | B | N |
| ATOM | 1644 | CA | LYS | B | 313 | 33.814 | 80.438 | 43.732 | 1.00 | 19.93 | B | C |
| ATOM | 1645 | CB | LYS | B | 313 | 33.233 | 81.771 | 44.200 | 1.00 | 23.32 | B | C |
| ATOM | 1646 | CG | LYS | B | 313 | 32.540 | 82.547 | 43.090 | 1.00 | 25.81 | B | C |
| ATOM | 1647 | CD | LYS | B | 313 | 32.307 | 83.985 | 43.488 | 1.00 | 30.35 | B | C |
| ATOM | 1648 | CE | LYS | B | 313 | 31.268 | 84.073 | 44.600 | 1.00 | 36.34 | B | C |
| ATOM | 1649 | NZ | LYS | B | 313 | 31.851 | 84.636 | 45.860 | 1.00 | 42.27 | B | N |
| ATOM | 1650 | C | LYS | B | 313 | 35.264 | 80.316 | 44.184 | 1.00 | 18.88 | B | C |
| ATOM | 1651 | O | LYS | B | 313 | 36.179 | 80.868 | 43.566 | 1.00 | 18.16 | B | O |
| ATOM | 1652 | N | HIS | B | 314 | 35.462 | 79.583 | 45.274 | 1.00 | 19.81 | B | N |
| ATOM | 1653 | CA | HIS | B | 314 | 36.789 | 79.354 | 45.826 | 1.00 | 18.25 | B | C |
| ATOM | 1654 | CB | HIS | B | 314 | 36.662 | 78.874 | 47.277 | 1.00 | 19.81 | B | C |
| ATOM | 1655 | CG | HIS | B | 314 | 37.969 | 78.586 | 47.947 | 1.00 | 21.61 | B | C |
| ATOM | 1656 | CD2 | HIS | B | 314 | 38.250 | 78.137 | 49.193 | 1.00 | 23.97 | B | C |
| ATOM | 1657 | ND1 | HIS | B | 314 | 39.186 | 78.739 | 47.314 | 1.00 | 24.52 | B | N |
| ATOM | 1658 | CE1 | HIS | B | 314 | 40.157 | 78.394 | 48.140 | 1.00 | 24.14 | B | C |
| ATOM | 1659 | NE2 | HIS | B | 314 | 39.617 | 78.026 | 49.288 | 1.00 | 26.91 | B | N |
| ATOM | 1660 | C | HIS | B | 314 | 37.462 | 78.289 | 44.957 | 1.00 | 17.08 | B | C |
| ATOM | 1661 | O | HIS | B | 314 | 38.642 | 78.394 | 44.628 | 1.00 | 17.02 | B | O |
| ATOM | 1662 | N | LEU | B | 315 | 36.707 | 77.264 | 44.581 | 1.00 | 15.41 | B | N |
| ATOM | 1663 | CA | LEU | B | 315 | 37.245 | 76.214 | 43.740 | 1.00 | 16.44 | B | C |
| ATOM | 1664 | CB | LEU | B | 315 | 36.226 | 75.085 | 43.573 | 1.00 | 17.59 | B | C |
| ATOM | 1665 | CG | LEU | B | 315 | 36.614 | 74.004 | 42.553 | 1.00 | 18.80 | B | C |
| ATOM | 1666 | CD1 | LEU | B | 315 | 37.902 | 73.306 | 43.013 | 1.00 | 16.38 | B | C |
| ATOM | 1667 | CD2 | LEU | B | 315 | 35.477 | 73.003 | 42.399 | 1.00 | 12.69 | B | C |
| ATOM | 1668 | C | LEU | B | 315 | 37.604 | 76.794 | 42.371 | 1.00 | 18.31 | B | C |
| ATOM | 1669 | O | LEU | B | 315 | 38.685 | 76.538 | 41.842 | 1.00 | 20.20 | B | O |
| ATOM | 1670 | N | LEU | B | 316 | 36.697 | 77.580 | 41.803 | 1.00 | 17.89 | B | N |
| ATOM | 1671 | CA | LEU | B | 316 | 36.922 | 78.197 | 40.500 | 1.00 | 19.09 | B | C |
| ATOM | 1672 | CB | LEU | B | 316 | 35.738 | 79.081 | 40.125 | 1.00 | 19.10 | B | C |
| ATOM | 1673 | CG | LEU | B | 316 | 35.803 | 79.667 | 38.714 | 1.00 | 19.18 | B | C |
| ATOM | 1674 | CD1 | LEU | B | 316 | 35.511 | 78.565 | 37.712 | 1.00 | 18.12 | B | C |
| ATOM | 1675 | CD2 | LEU | B | 316 | 34.792 | 80.793 | 38.564 | 1.00 | 15.19 | B | C |
| ATOM | 1676 | C | LEU | B | 316 | 38.186 | 79.040 | 40.502 | 1.00 | 20.47 | B | C |
| ATOM | 1677 | O | LEU | B | 316 | 38.992 | 78.990 | 39.582 | 1.00 | 22.34 | B | O |
| ATOM | 1678 | N | ARG | B | 317 | 38.346 | 79.828 | 41.550 | 1.00 | 23.32 | B | N |
| ATOM | 1679 | CA | ARG | B | 317 | 39.505 | 80.690 | 41.699 | 1.00 | 23.73 | B | C |
| ATOM | 1680 | CB | ARG | B | 317 | 39.353 | 81.492 | 42.992 | 1.00 | 27.00 | B | C |
| ATOM | 1681 | CG | ARG | B | 317 | 40.393 | 82.564 | 43.215 | 1.00 | 32.62 | B | C |
| ATOM | 1682 | CD | ARG | B | 317 | 39.900 | 83.587 | 44.235 | 1.00 | 37.03 | B | C |
| ATOM | 1683 | NE | ARG | B | 317 | 39.417 | 82.969 | 45.473 | 1.00 | 39.86 | B | N |
| ATOM | 1684 | CZ | ARG | B | 317 | 38.184 | 83.122 | 45.950 | 1.00 | 39.91 | B | C |
| ATOM | 1685 | NH1 | ARG | B | 317 | 37.309 | 83.871 | 45.293 | 1.00 | 40.57 | B | N |
| ATOM | 1686 | NH2 | ARG | B | 317 | 37.827 | 82.534 | 47.084 | 1.00 | 39.50 | B | N |
| ATOM | 1687 | C | ARG | B | 317 | 40.803 | 79.882 | 41.732 | 1.00 | 22.18 | B | C |
| ATOM | 1688 | O | ARG | B | 317 | 41.800 | 80.273 | 41.135 | 1.00 | 21.93 | B | O |
| ATOM | 1689 | N | PHE | B | 318 | 40.789 | 78.750 | 42.426 | 1.00 | 22.23 | B | N |
| ATOM | 1690 | CA | PHE | B | 318 | 41.984 | 77.923 | 42.540 | 1.00 | 20.18 | B | C |
| ATOM | 1691 | CB | PHE | B | 318 | 41.830 | 76.912 | 43.675 | 1.00 | 19.03 | B | C |
| ATOM | 1692 | CG | PHE | B | 318 | 43.002 | 75.978 | 43.811 | 1.00 | 19.71 | B | C |
| ATOM | 1693 | CD1 | PHE | B | 318 | 44.071 | 76.296 | 44.640 | 1.00 | 19.47 | B | C |
| ATOM | 1694 | CD2 | PHE | B | 318 | 43.045 | 74.783 | 43.093 | 1.00 | 21.06 | B | C |
| ATOM | 1695 | CE1 | PHE | B | 318 | 45.174 | 75.439 | 44.756 | 1.00 | 17.61 | B | C |
| ATOM | 1696 | CE2 | PHE | B | 318 | 44.140 | 73.920 | 43.199 | 1.00 | 18.70 | B | C |
| ATOM | 1697 | CZ | PHE | B | 318 | 45.208 | 74.251 | 44.034 | 1.00 | 16.32 | B | C |
| ATOM | 1698 | C | PHE | B | 318 | 42.331 | 77.181 | 41.258 | 1.00 | 21.95 | B | C |
| ATOM | 1699 | O | PHE | B | 318 | 43.507 | 76.956 | 40.959 | 1.00 | 21.03 | B | O |
| ATOM | 1700 | N | ILE | B | 319 | 41.318 | 76.777 | 40.505 | 1.00 | 21.84 | B | N |
| ATOM | 1701 | CA | ILE | B | 319 | 41.586 | 76.070 | 39.265 | 1.00 | 20.33 | B | C |
| ATOM | 1702 | CB | ILE | B | 319 | 40.284 | 75.639 | 38.577 | 1.00 | 16.16 | B | C |
| ATOM | 1703 | CG2 | ILE | B | 319 | 40.587 | 75.113 | 37.183 | 1.00 | 17.32 | B | C |
| ATOM | 1704 | CG1 | ILE | B | 319 | 39.593 | 74.569 | 39.422 | 1.00 | 11.49 | B | C |
| ATOM | 1705 | CD1 | ILE | B | 319 | 38.301 | 74.070 | 38.847 | 1.00 | 10.07 | B | C |
| ATOM | 1706 | C | ILE | B | 319 | 42.388 | 76.988 | 38.345 | 1.00 | 21.72 | B | C |
| ATOM | 1707 | O | ILE | B | 319 | 43.430 | 76.590 | 37.810 | 1.00 | 20.33 | B | O |
| ATOM | 1708 | N | LYS | B | 320 | 41.915 | 78.221 | 38.186 | 1.00 | 18.47 | B | N |
| ATOM | 1709 | CA | LYS | B | 320 | 42.587 | 79.189 | 37.334 | 1.00 | 20.50 | B | C |
| ATOM | 1710 | CB | LYS | B | 320 | 41.789 | 80.489 | 37.282 | 1.00 | 18.65 | B | C |
| ATOM | 1711 | CG | LYS | B | 320 | 40.371 | 80.314 | 36.770 | 1.00 | 18.68 | B | C |
| ATOM | 1712 | CD | LYS | B | 320 | 39.718 | 81.654 | 36.509 | 1.00 | 15.49 | B | C |
| ATOM | 1713 | CE | LYS | B | 320 | 38.369 | 81.489 | 35.848 | 1.00 | 18.68 | B | C |
| ATOM | 1714 | NZ | LYS | B | 320 | 37.583 | 82.746 | 35.906 | 1.00 | 24.35 | B | N |
| ATOM | 1715 | C | LYS | B | 320 | 44.005 | 79.471 | 37.822 | 1.00 | 22.19 | B | C |
| ATOM | 1716 | O | LYS | B | 320 | 44.941 | 79.566 | 37.029 | 1.00 | 23.86 | B | O |
| ATOM | 1717 | N | LYS | B | 321 | 44.165 | 79.603 | 39.130 | 1.00 | 22.15 | B | N |
| ATOM | 1718 | CA | LYS | B | 321 | 45.477 | 79.868 | 39.697 | 1.00 | 22.58 | B | C |
| ATOM | 1719 | CB | LYS | B | 321 | 45.358 | 80.117 | 41.201 | 1.00 | 22.00 | B | C |
| ATOM | 1720 | CG | LYS | B | 321 | 46.571 | 80.793 | 41.822 | 1.00 | 28.30 | B | C |
| ATOM | 1721 | CD | LYS | B | 321 | 46.911 | 82.100 | 41.112 | 1.00 | 34.77 | B | C |
| ATOM | 1722 | CE | LYS | B | 321 | 48.043 | 82.851 | 41.814 | 1.00 | 36.91 | B | C |
| ATOM | 1723 | NZ | LYS | B | 321 | 48.986 | 81.940 | 42.528 | 1.00 | 38.87 | B | N |
| ATOM | 1724 | C | LYS | B | 321 | 46.427 | 78.703 | 39.437 | 1.00 | 23.75 | B | C |
| ATOM | 1725 | O | LYS | B | 321 | 47.604 | 78.907 | 39.151 | 1.00 | 24.77 | B | O |
| ATOM | 1726 | N | SER | B | 322 | 45.916 | 77.481 | 39.534 | 1.00 | 23.84 | B | N |
| ATOM | 1727 | CA | SER | B | 322 | 46.741 | 76.299 | 39.312 | 1.00 | 23.08 | B | C |
| ATOM | 1728 | CB | SER | B | 322 | 45.948 | 75.023 | 39.627 | 1.00 | 17.97 | B | C |
| ATOM | 1729 | OG | SER | B | 322 | 44.933 | 74.789 | 38.669 | 1.00 | 17.77 | B | O |
| ATOM | 1730 | C | SER | B | 322 | 47.261 | 76.252 | 37.876 | 1.00 | 27.06 | B | C |
| ATOM | 1731 | O | SER | B | 322 | 48.377 | 75.792 | 37.624 | 1.00 | 24.99 | B | O |
| ATOM | 1732 | N | TYR | B | 323 | 46.455 | 76.730 | 36.933 | 1.00 | 30.13 | B | N |
| ATOM | 1733 | CA | TYR | B | 323 | 46.861 | 76.736 | 35.531 | 1.00 | 30.99 | B | C |
| ATOM | 1734 | CB | TYR | B | 323 | 45.666 | 77.045 | 34.635 | 1.00 | 32.58 | B | C |
| ATOM | 1735 | CG | TYR | B | 323 | 46.009 | 77.083 | 33.166 | 1.00 | 35.78 | B | C |
| ATOM | 1736 | CD1 | TYR | B | 323 | 46.376 | 78.276 | 32.548 | 1.00 | 36.89 | B | C |
| ATOM | 1737 | CE1 | TYR | B | 323 | 46.683 | 78.322 | 31.192 | 1.00 | 38.23 | B | C |
| ATOM | 1738 | CD2 | TYR | B | 323 | 45.958 | 75.926 | 32.390 | 1.00 | 36.46 | B | C |
| ATOM | 1739 | CE2 | TYR | B | 323 | 46.262 | 75.958 | 31.036 | 1.00 | 38.95 | B | C |
| ATOM | 1740 | CZ | TYR | B | 323 | 46.624 | 77.160 | 30.442 | 1.00 | 40.91 | B | C |
| ATOM | 1741 | OH | TYR | B | 323 | 46.921 | 77.198 | 29.096 | 1.00 | 45.15 | B | O |
| ATOM | 1742 | C | TYR | B | 323 | 47.945 | 77.781 | 35.308 | 1.00 | 30.05 | B | C |
| ATOM | 1743 | O | TYR | B | 323 | 48.923 | 77.549 | 34.602 | 1.00 | 29.44 | B | O |
| ATOM | 1744 | N | GLN | B | 324 | 47.758 | 78.938 | 35.923 | 1.00 | 30.81 | B | N |
| ATOM | 1745 | CA | GLN | B | 324 | 48.704 | 80.031 | 35.799 | 1.00 | 31.54 | B | C |
| ATOM | 1746 | CB | GLN | B | 324 | 48.210 | 81.232 | 36.613 | 1.00 | 33.76 | B | C |
| ATOM | 1747 | CG | GLN | B | 324 | 49.207 | 82.368 | 36.765 | 1.00 | 38.62 | B | C |
| ATOM | 1748 | CD | GLN | B | 324 | 48.981 | 83.180 | 38.037 | 1.00 | 43.88 | B | C |
| ATOM | 1749 | OE1 | GLN | B | 324 | 47.867 | 83.642 | 38.306 | 1.00 | 45.25 | B | O |
| ATOM | 1750 | NE2 | GLN | B | 324 | 50.040 | 83.353 | 38.827 | 1.00 | 42.78 | B | N |
| ATOM | 1751 | C | GLN | B | 324 | 50.107 | 79.633 | 36.249 | 1.00 | 29.89 | B | C |
| ATOM | 1752 | O | GLN | B | 324 | 51.094 | 80.068 | 35.660 | 1.00 | 30.32 | B | O |
| ATOM | 1753 | N | VAL | B | 325 | 50.203 | 78.793 | 37.274 | 1.00 | 29.45 | B | N |
| ATOM | 1754 | CA | VAL | B | 325 | 51.518 | 78.396 | 37.780 | 1.00 | 27.33 | B | C |
| ATOM | 1755 | CB | VAL | B | 325 | 51.631 | 78.643 | 39.321 | 1.00 | 23.91 | B | C |
| ATOM | 1756 | CG1 | VAL | B | 325 | 50.760 | 79.811 | 39.732 | 1.00 | 22.90 | B | C |
| ATOM | 1757 | CG2 | VAL | B | 325 | 51.246 | 77.401 | 40.087 | 1.00 | 25.28 | B | C |
| ATOM | 1758 | C | VAL | B | 325 | 51.976 | 76.965 | 37.489 | 1.00 | 27.54 | B | C |
| ATOM | 1759 | O | VAL | B | 325 | 53.172 | 76.682 | 37.533 | 1.00 | 27.83 | B | O |
| ATOM | 1760 | N | ASP | B | 326 | 51.046 | 76.064 | 37.193 | 1.00 | 28.01 | B | N |
| ATOM | 1761 | CA | ASP | B | 326 | 51.417 | 74.675 | 36.921 | 1.00 | 25.92 | B | C |
| ATOM | 1762 | CB | ASP | B | 326 | 50.787 | 73.740 | 37.964 | 1.00 | 27.07 | B | C |
| ATOM | 1763 | CG | ASP | B | 326 | 51.557 | 73.712 | 39.280 | 1.00 | 27.32 | B | C |
| ATOM | 1764 | OD1 | ASP | B | 326 | 52.691 | 74.241 | 39.338 | 1.00 | 26.89 | B | O |
| ATOM | 1765 | OD2 | ASP | B | 326 | 51.021 | 73.155 | 40.265 | 1.00 | 26.71 | B | O |
| ATOM | 1766 | C | ASP | B | 326 | 50.967 | 74.233 | 35.537 | 1.00 | 26.71 | B | C |
| ATOM | 1767 | O | ASP | B | 326 | 50.792 | 73.043 | 35.299 | 1.00 | 29.00 | B | O |
| ATOM | 1768 | N | ALA | B | 327 | 50.778 | 75.184 | 34.627 | 1.00 | 26.18 | B | N |
| ATOM | 1769 | CA | ALA | B | 327 | 50.326 | 74.867 | 33.275 | 1.00 | 27.92 | B | C |
| ATOM | 1770 | CB | ALA | B | 327 | 50.377 | 76.117 | 32.403 | 1.00 | 24.12 | B | C |
| ATOM | 1771 | C | ALA | B | 327 | 51.111 | 73.737 | 32.605 | 1.00 | 30.59 | B | C |
| ATOM | 1772 | O | ALA | B | 327 | 50.534 | 72.924 | 31.863 | 1.00 | 29.53 | B | O |
| ATOM | 1773 | N | ASP | B | 328 | 52.414 | 73.675 | 32.873 | 1.00 | 30.19 | B | N |
| ATOM | 1774 | CA | ASP | B | 328 | 53.264 | 72.654 | 32.261 | 1.00 | 34.59 | B | C |
| ATOM | 1775 | CB | ASP | B | 328 | 54.492 | 73.313 | 31.621 | 1.00 | 36.42 | B | C |
| ATOM | 1776 | CG | ASP | B | 328 | 54.117 | 74.324 | 30.542 | 1.00 | 41.64 | B | C |
| ATOM | 1777 | OD1 | ASP | B | 328 | 53.327 | 73.978 | 29.630 | 1.00 | 39.53 | B | O |
| ATOM | 1778 | OD2 | ASP | B | 328 | 54.614 | 75.470 | 30.611 | 1.00 | 42.69 | B | O |
| ATOM | 1779 | C | ASP | B | 328 | 53.718 | 71.530 | 33.189 | 1.00 | 34.80 | B | C |
| ATOM | 1780 | O | ASP | B | 328 | 54.651 | 70.795 | 32.869 | 1.00 | 35.35 | B | O |
| ATOM | 1781 | N | ARG | B | 329 | 53.053 | 71.397 | 34.333 | 1.00 | 32.77 | B | N |
| ATOM | 1782 | CA | ARG | B | 329 | 53.373 | 70.353 | 35.299 | 1.00 | 28.99 | B | C |
| ATOM | 1783 | CB | ARG | B | 329 | 52.837 | 70.741 | 36.687 | 1.00 | 30.01 | B | C |
| ATOM | 1784 | CG | ARG | B | 329 | 53.674 | 70.270 | 37.868 | 1.00 | 29.41 | B | C |
| ATOM | 1785 | CD | ARG | B | 329 | 52.860 | 69.436 | 38.858 | 1.00 | 31.45 | B | C |
| ATOM | 1786 | NE | ARG | B | 329 | 52.409 | 70.222 | 40.005 | 1.00 | 31.20 | B | N |
| ATOM | 1787 | CZ | ARG | B | 329 | 52.372 | 69.788 | 41.263 | 1.00 | 30.62 | B | C |
| ATOM | 1788 | NH1 | ARG | B | 329 | 52.754 | 68.560 | 41.568 | 1.00 | 31.76 | B | N |
| ATOM | 1789 | NH2 | ARG | B | 329 | 51.929 | 70.584 | 42.222 | 1.00 | 31.93 | B | N |
| ATOM | 1790 | C | ARG | B | 329 | 52.697 | 69.067 | 34.847 | 1.00 | 27.45 | B | C |
| ATOM | 1791 | O | ARG | B | 329 | 51.541 | 69.093 | 34.417 | 1.00 | 24.31 | B | O |
| ATOM | 1792 | N | VAL | B | 330 | 53.414 | 67.947 | 34.923 | 1.00 | 27.26 | B | N |
| ATOM | 1793 | CA | VAL | B | 330 | 52.817 | 66.667 | 34.552 | 1.00 | 28.13 | B | C |
| ATOM | 1794 | CB | VAL | B | 330 | 53.869 | 65.557 | 34.423 | 1.00 | 27.49 | B | C |
| ATOM | 1795 | CG1 | VAL | B | 330 | 53.183 | 64.227 | 34.114 | 1.00 | 25.12 | B | C |
| ATOM | 1796 | CG2 | VAL | B | 330 | 54.846 | 65.909 | 33.327 | 1.00 | 23.10 | B | C |
| ATOM | 1797 | C | VAL | B | 330 | 51.889 | 66.364 | 35.719 | 1.00 | 29.01 | B | C |
| ATOM | 1798 | O | VAL | B | 330 | 52.329 | 66.261 | 36.869 | 1.00 | 28.49 | B | O |
| ATOM | 1799 | N | VAL | B | 331 | 50.605 | 66.221 | 35.428 | 1.00 | 29.37 | B | N |
| ATOM | 1800 | CA | VAL | B | 331 | 49.638 | 66.015 | 36.489 | 1.00 | 29.76 | B | C |
| ATOM | 1801 | CB | VAL | B | 331 | 48.853 | 67.330 | 36.689 | 1.00 | 29.23 | B | C |
| ATOM | 1802 | CG1 | VAL | B | 331 | 47.570 | 67.306 | 35.888 | 1.00 | 27.11 | B | C |
| ATOM | 1803 | CG2 | VAL | B | 331 | 48.592 | 67.555 | 38.151 | 1.00 | 35.23 | B | C |
| ATOM | 1804 | C | VAL | B | 331 | 48.666 | 64.857 | 36.302 | 1.00 | 28.67 | B | C |
| ATOM | 1805 | O | VAL | B | 331 | 48.009 | 64.431 | 37.251 | 1.00 | 27.30 | B | O |
| ATOM | 1806 | N | TYR | B | 332 | 48.586 | 64.344 | 35.081 | 1.00 | 30.15 | B | N |
| ATOM | 1807 | CA | TYR | B | 332 | 47.673 | 63.256 | 34.759 | 1.00 | 33.33 | B | C |
| ATOM | 1808 | CB | TYR | B | 332 | 46.532 | 63.819 | 33.914 | 1.00 | 31.15 | B | C |
| ATOM | 1809 | CG | TYR | B | 332 | 45.485 | 62.833 | 33.457 | 1.00 | 32.84 | B | C |
| ATOM | 1810 | CD1 | TYR | B | 332 | 44.337 | 62.603 | 34.216 | 1.00 | 32.96 | B | C |
| ATOM | 1811 | CE1 | TYR | B | 332 | 43.326 | 61.761 | 33.758 | 1.00 | 34.86 | B | C |
| ATOM | 1812 | CD2 | TYR | B | 332 | 45.600 | 62.188 | 32.224 | 1.00 | 34.71 | B | C |
| ATOM | 1813 | CE2 | TYR | B | 332 | 44.592 | 61.342 | 31.754 | 1.00 | 35.87 | B | C |
| ATOM | 1814 | CZ | TYR | B | 332 | 43.457 | 61.136 | 32.526 | 1.00 | 36.07 | B | C |
| ATOM | 1815 | OH | TYR | B | 332 | 42.450 | 60.319 | 32.060 | 1.00 | 38.00 | B | O |
| ATOM | 1816 | C | TYR | B | 332 | 48.425 | 62.172 | 33.999 | 1.00 | 36.90 | B | C |
| ATOM | 1817 | O | TYR | B | 332 | 49.383 | 62.464 | 33.288 | 1.00 | 38.11 | B | O |
| ATOM | 1818 | N | SER | B | 333 | 48.000 | 60.921 | 34.144 | 1.00 | 41.10 | B | N |
| ATOM | 1819 | CA | SER | B | 333 | 48.679 | 59.833 | 33.453 | 1.00 | 43.78 | B | C |
| ATOM | 1820 | CB | SER | B | 333 | 49.163 | 58.788 | 34.458 | 1.00 | 45.05 | B | C |
| ATOM | 1821 | OG | SER | B | 333 | 49.534 | 57.595 | 33.788 | 1.00 | 46.10 | B | O |
| ATOM | 1822 | C | SER | B | 333 | 47.841 | 59.143 | 32.383 | 1.00 | 46.86 | B | C |
| ATOM | 1823 | O | SER | B | 333 | 46.737 | 58.662 | 32.649 | 1.00 | 45.71 | B | O |
| ATOM | 1824 | N | THR | B | 334 | 48.377 | 59.114 | 31.166 | 1.00 | 49.21 | B | N |
| ATOM | 1825 | CA | THR | B | 334 | 47.726 | 58.458 | 30.036 | 1.00 | 53.47 | B | C |
| ATOM | 1826 | CB | THR | B | 334 | 47.122 | 59.475 | 29.028 | 1.00 | 53.52 | B | C |
| ATOM | 1827 | OG1 | THR | B | 334 | 45.721 | 59.212 | 28.884 | 1.00 | 53.44 | B | O |
| ATOM | 1828 | CG2 | THR | B | 334 | 47.786 | 59.357 | 27.655 | 1.00 | 52.85 | B | C |
| ATOM | 1829 | C | THR | B | 334 | 48.793 | 57.621 | 29.348 | 1.00 | 56.01 | B | C |
| ATOM | 1830 | O | THR | B | 334 | 49.952 | 58.032 | 29.254 | 1.00 | 55.31 | B | O |
| ATOM | 1831 | N | LYS | B | 335 | 48.392 | 56.447 | 28.872 | 1.00 | 57.92 | B | N |
| ATOM | 1832 | CA | LYS | B | 335 | 49.305 | 55.520 | 28.215 | 1.00 | 59.57 | B | C |
| ATOM | 1833 | CB | LYS | B | 335 | 48.529 | 54.579 | 27.295 | 1.00 | 56.63 | B | C |
| ATOM | 1834 | CG | LYS | B | 335 | 49.075 | 53.156 | 27.282 | 1.00 | 53.97 | B | C |
| ATOM | 1835 | CD | LYS | B | 335 | 50.575 | 53.095 | 26.986 | 1.00 | 49.70 | B | C |
| ATOM | 1836 | CE | LYS | B | 335 | 51.305 | 52.218 | 27.997 | 1.00 | 48.07 | B | C |
| ATOM | 1837 | NZ | LYS | B | 335 | 52.321 | 51.323 | 27.372 | 1.00 | 46.05 | B | N |
| ATOM | 1838 | C | LYS | B | 335 | 50.454 | 56.151 | 27.431 | 1.00 | 62.18 | B | C |
| ATOM | 1839 | O | LYS | B | 335 | 51.546 | 56.359 | 27.971 | 1.00 | 64.82 | B | O |
| ATOM | 1840 | N | GLU | B | 336 | 50.209 | 56.450 | 26.158 | 1.00 | 62.33 | B | N |
| ATOM | 1841 | CA | GLU | B | 336 | 51.244 | 57.023 | 25.302 | 1.00 | 62.22 | B | C |
| ATOM | 1842 | CB | GLU | B | 336 | 50.699 | 57.258 | 23.889 | 1.00 | 65.07 | B | C |
| ATOM | 1843 | CG | GLU | B | 336 | 51.568 | 56.644 | 22.785 | 1.00 | 68.83 | B | C |
| ATOM | 1844 | CD | GLU | B | 336 | 52.635 | 55.684 | 23.321 | 1.00 | 70.62 | B | C |
| ATOM | 1845 | OE1 | GLU | B | 336 | 53.745 | 56.151 | 23.674 | 1.00 | 69.80 | B | O |
| ATOM | 1846 | OE2 | GLU | B | 336 | 52.359 | 54.462 | 23.387 | 1.00 | 69.02 | B | O |
| ATOM | 1847 | C | GLU | B | 336 | 51.878 | 58.305 | 25.827 | 1.00 | 60.11 | B | C |
| ATOM | 1848 | O | GLU | B | 336 | 52.928 | 58.726 | 25.335 | 1.00 | 59.38 | B | O |
| ATOM | 1849 | N | LYS | B | 337 | 51.253 | 58.923 | 26.827 | 1.00 | 57.71 | B | N |
| ATOM | 1850 | CA | LYS | B | 337 | 51.806 | 60.145 | 27.389 | 1.00 | 53.49 | B | C |
| ATOM | 1851 | CB | LYS | B | 337 | 51.862 | 61.234 | 26.313 | 1.00 | 53.36 | B | C |
| ATOM | 1852 | CG | LYS | B | 337 | 52.670 | 62.456 | 26.706 | 1.00 | 52.64 | B | C |
| ATOM | 1853 | CD | LYS | B | 337 | 52.370 | 63.633 | 25.791 | 1.00 | 52.20 | B | C |
| ATOM | 1854 | CE | LYS | B | 337 | 52.812 | 64.942 | 26.427 | 1.00 | 55.15 | B | C |
| ATOM | 1855 | NZ | LYS | B | 337 | 54.030 | 65.524 | 25.790 | 1.00 | 52.07 | B | N |
| ATOM | 1856 | C | LYS | B | 337 | 51.047 | 60.675 | 28.593 | 1.00 | 51.28 | B | C |
| ATOM | 1857 | O | LYS | B | 337 | 49.832 | 60.877 | 28.538 | 1.00 | 51.53 | B | O |
| ATOM | 1858 | N | ASN | B | 338 | 51.767 | 60.885 | 29.690 | 1.00 | 47.96 | B | N |
| ATOM | 1859 | CA | ASN | B | 338 | 51.154 | 61.447 | 30.880 | 1.00 | 45.20 | B | C |
| ATOM | 1860 | CB | ASN | B | 338 | 52.107 | 61.359 | 32.072 | 1.00 | 45.24 | B | C |
| ATOM | 1861 | CG | ASN | B | 338 | 52.523 | 59.929 | 32.383 | 1.00 | 44.57 | B | C |
| ATOM | 1862 | OD1 | ASN | B | 338 | 51.702 | 59.004 | 32.347 | 1.00 | 43.83 | B | O |
| ATOM | 1863 | ND2 | ASN | B | 338 | 53.802 | 59.740 | 32.691 | 1.00 | 41.25 | B | N |
| ATOM | 1864 | C | ASN | B | 338 | 50.980 | 62.892 | 30.433 | 1.00 | 43.27 | B | C |
| ATOM | 1865 | O | ASN | B | 338 | 51.829 | 63.414 | 29.712 | 1.00 | 39.01 | B | O |
| ATOM | 1866 | N | LEU | B | 339 | 49.891 | 63.535 | 30.838 | 1.00 | 39.85 | B | N |
| ATOM | 1867 | CA | LEU | B | 339 | 49.642 | 64.903 | 30.405 | 1.00 | 34.43 | B | C |
| ATOM | 1868 | CB | LEU | B | 339 | 48.170 | 65.066 | 30.034 | 1.00 | 33.37 | B | C |
| ATOM | 1869 | CG | LEU | B | 339 | 47.511 | 63.827 | 29.439 | 1.00 | 36.45 | B | C |
| ATOM | 1870 | CD1 | LEU | B | 339 | 45.999 | 63.994 | 29.441 | 1.00 | 33.73 | B | C |
| ATOM | 1871 | CD2 | LEU | B | 339 | 48.041 | 63.609 | 28.028 | 1.00 | 32.48 | B | C |
| ATOM | 1872 | C | LEU | B | 339 | 50.003 | 65.968 | 31.412 | 1.00 | 33.34 | B | C |
| ATOM | 1873 | O | LEU | B | 339 | 50.080 | 65.710 | 32.610 | 1.00 | 34.91 | B | O |
| ATOM | 1874 | N | THR | B | 340 | 50.237 | 67.173 | 30.908 | 1.00 | 31.71 | B | N |
| ATOM | 1875 | CA | THR | B | 340 | 50.528 | 68.312 | 31.761 | 1.00 | 29.66 | B | C |
| ATOM | 1876 | CB | THR | B | 340 | 51.373 | 69.375 | 31.040 | 1.00 | 30.18 | B | C |
| ATOM | 1877 | OG1 | THR | B | 340 | 50.671 | 69.840 | 29.885 | 1.00 | 30.61 | B | O |
| ATOM | 1878 | CG2 | THR | B | 340 | 52.710 | 68.805 | 30.625 | 1.00 | 27.56 | B | C |
| ATOM | 1879 | C | THR | B | 340 | 49.153 | 68.899 | 32.048 | 1.00 | 28.94 | B | C |
| ATOM | 1880 | O | THR | B | 340 | 48.162 | 68.491 | 31.431 | 1.00 | 28.01 | B | O |
| ATOM | 1881 | N | LEU | B | 341 | 49.080 | 69.840 | 32.982 | 1.00 | 29.78 | B | N |
| ATOM | 1882 | CA | LEU | B | 341 | 47.801 | 70.459 | 33.314 | 1.00 | 29.20 | B | C |
| ATOM | 1883 | CB | LEU | B | 341 | 48.005 | 71.593 | 34.324 | 1.00 | 29.00 | B | C |
| ATOM | 1884 | CG | LEU | B | 341 | 46.752 | 72.322 | 34.822 | 1.00 | 29.43 | B | C |
| ATOM | 1885 | CD1 | LEU | B | 341 | 45.669 | 71.313 | 35.192 | 1.00 | 28.33 | B | C |
| ATOM | 1886 | CD2 | LEU | B | 341 | 47.116 | 73.185 | 36.016 | 1.00 | 23.15 | B | C |
| ATOM | 1887 | C | LEU | B | 341 | 47.172 | 71.008 | 32.035 | 1.00 | 30.38 | B | C |
| ATOM | 1888 | O | LEU | B | 341 | 45.976 | 70.830 | 31.789 | 1.00 | 29.72 | B | O |
| ATOM | 1889 | N | LYS | B | 342 | 47.996 | 71.662 | 31.219 | 1.00 | 30.43 | B | N |
| ATOM | 1890 | CA | LYS | B | 342 | 47.545 | 72.239 | 29.961 | 1.00 | 28.42 | B | C |
| ATOM | 1891 | CB | LYS | B | 342 | 48.704 | 72.948 | 29.275 | 1.00 | 29.65 | B | C |
| ATOM | 1892 | CG | LYS | B | 342 | 48.278 | 73.921 | 28.194 | 1.00 | 33.59 | B | C |
| ATOM | 1893 | CD | LYS | B | 342 | 49.489 | 74.627 | 27.585 | 1.00 | 39.33 | B | C |
| ATOM | 1894 | CE | LYS | B | 342 | 49.181 | 76.077 | 27.212 | 1.00 | 43.19 | B | C |
| ATOM | 1895 | NZ | LYS | B | 342 | 49.944 | 77.060 | 28.046 | 1.00 | 45.31 | B | N |
| ATOM | 1896 | C | LYS | B | 342 | 46.980 | 71.178 | 29.032 | 1.00 | 28.08 | B | C |
| ATOM | 1897 | O | LYS | B | 342 | 45.879 | 71.330 | 28.504 | 1.00 | 28.45 | B | O |
| ATOM | 1898 | N | GLN | B | 343 | 47.733 | 70.101 | 28.842 | 1.00 | 26.59 | B | N |
| ATOM | 1899 | CA | GLN | B | 343 | 47.305 | 69.019 | 27.965 | 1.00 | 29.13 | B | C |
| ATOM | 1900 | CB | GLN | B | 343 | 48.383 | 67.946 | 27.884 | 1.00 | 30.96 | B | C |
| ATOM | 1901 | CG | GLN | B | 343 | 49.613 | 68.371 | 27.114 | 1.00 | 31.09 | B | C |
| ATOM | 1902 | CD | GLN | B | 343 | 50.735 | 67.374 | 27.252 | 1.00 | 35.29 | B | C |
| ATOM | 1903 | OE1 | GLN | B | 343 | 50.531 | 66.257 | 27.732 | 1.00 | 41.42 | B | O |
| ATOM | 1904 | NE2 | GLN | B | 343 | 51.928 | 67.764 | 26.831 | 1.00 | 33.15 | B | N |
| ATOM | 1905 | C | GLN | B | 343 | 46.011 | 68.380 | 28.422 | 1.00 | 29.18 | B | C |
| ATOM | 1906 | O | GLN | B | 343 | 45.205 | 67.937 | 27.600 | 1.00 | 30.88 | B | O |
| ATOM | 1907 | N | LEU | B | 344 | 45.820 | 68.318 | 29.735 | 1.00 | 28.82 | B | N |
| ATOM | 1908 | CA | LEU | B | 344 | 44.611 | 67.725 | 30.283 | 1.00 | 27.33 | B | C |
| ATOM | 1909 | CB | LEU | B | 344 | 44.720 | 67.605 | 31.807 | 1.00 | 25.61 | B | C |
| ATOM | 1910 | CG | LEU | B | 344 | 43.503 | 66.998 | 32.514 | 1.00 | 25.90 | B | C |
| ATOM | 1911 | CD1 | LEU | B | 344 | 43.079 | 65.709 | 31.812 | 1.00 | 21.63 | B | C |
| ATOM | 1912 | CD2 | LEU | B | 344 | 43.839 | 66.740 | 33.979 | 1.00 | 23.42 | B | C |
| ATOM | 1913 | C | LEU | B | 344 | 43.417 | 68.588 | 29.901 | 1.00 | 24.32 | B | C |
| ATOM | 1914 | O | LEU | B | 344 | 42.379 | 68.080 | 29.484 | 1.00 | 23.29 | B | O |
| ATOM | 1915 | N | PHE | B | 345 | 43.573 | 69.898 | 30.033 | 1.00 | 24.54 | B | N |
| ATOM | 1916 | CA | PHE | B | 345 | 42.495 | 70.816 | 29.685 | 1.00 | 28.34 | B | C |
| ATOM | 1917 | CB | PHE | B | 345 | 42.825 | 72.230 | 30.171 | 1.00 | 24.50 | B | C |
| ATOM | 1918 | CG | PHE | B | 345 | 42.500 | 72.457 | 31.621 | 1.00 | 21.31 | B | C |
| ATOM | 1919 | CD1 | PHE | B | 345 | 41.193 | 72.338 | 32.082 | 1.00 | 22.49 | B | C |
| ATOM | 1920 | CD2 | PHE | B | 345 | 43.500 | 72.767 | 32.532 | 1.00 | 22.31 | B | C |
| ATOM | 1921 | CE1 | PHE | B | 345 | 40.890 | 72.522 | 33.430 | 1.00 | 21.08 | B | C |
| ATOM | 1922 | CE2 | PHE | B | 345 | 43.205 | 72.954 | 33.883 | 1.00 | 20.96 | B | C |
| ATOM | 1923 | CZ | PHE | B | 345 | 41.896 | 72.830 | 34.330 | 1.00 | 19.30 | B | C |
| ATOM | 1924 | C | PHE | B | 345 | 42.250 | 70.808 | 28.177 | 1.00 | 29.77 | B | C |
| ATOM | 1925 | O | PHE | B | 345 | 41.126 | 71.043 | 27.722 | 1.00 | 30.50 | B | O |
| ATOM | 1926 | N | ASP | B | 346 | 43.303 | 70.533 | 27.408 | 1.00 | 31.81 | B | N |
| ATOM | 1927 | CA | ASP | B | 346 | 43.199 | 70.458 | 25.953 | 1.00 | 32.02 | B | C |
| ATOM | 1928 | CB | ASP | B | 346 | 44.578 | 70.293 | 25.324 | 1.00 | 37.28 | B | C |
| ATOM | 1929 | CG | ASP | B | 346 | 45.221 | 71.615 | 24.974 | 1.00 | 41.66 | B | C |
| ATOM | 1930 | OD1 | ASP | B | 346 | 44.669 | 72.668 | 25.362 | 1.00 | 43.53 | B | O |
| ATOM | 1931 | OD2 | ASP | B | 346 | 46.285 | 71.598 | 24.314 | 1.00 | 43.83 | B | O |
| ATOM | 1932 | C | ASP | B | 346 | 42.361 | 69.238 | 25.614 | 1.00 | 31.20 | B | C |
| ATOM | 1933 | O | ASP | B | 346 | 41.483 | 69.288 | 24.764 | 1.00 | 31.94 | B | O |
| ATOM | 1934 | N | LYS | B | 347 | 42.657 | 68.139 | 26.290 | 1.00 | 31.01 | B | N |
| ATOM | 1935 | CA | LYS | B | 347 | 41.945 | 66.887 | 26.102 | 1.00 | 32.37 | B | C |
| ATOM | 1936 | CB | LYS | B | 347 | 42.609 | 65.798 | 26.952 | 1.00 | 34.48 | B | C |
| ATOM | 1937 | CG | LYS | B | 347 | 42.218 | 64.380 | 26.593 | 1.00 | 40.04 | B | C |
| ATOM | 1938 | CD | LYS | B | 347 | 41.468 | 63.713 | 27.736 | 1.00 | 44.70 | B | C |
| ATOM | 1939 | CE | LYS | B | 347 | 42.321 | 62.668 | 28.429 | 1.00 | 45.23 | B | C |
| ATOM | 1940 | NZ | LYS | B | 347 | 41.720 | 61.311 | 28.321 | 1.00 | 46.28 | B | N |
| ATOM | 1941 | C | LYS | B | 347 | 40.481 | 67.046 | 26.510 | 1.00 | 32.60 | B | C |
| ATOM | 1942 | O | LYS | B | 347 | 39.603 | 66.351 | 25.999 | 1.00 | 34.96 | B | O |
| ATOM | 1943 | N | LEU | B | 348 | 40.222 | 67.963 | 27.437 | 1.00 | 31.67 | B | N |
| ATOM | 1944 | CA | LEU | B | 348 | 38.868 | 68.197 | 27.912 | 1.00 | 32.42 | B | C |
| ATOM | 1945 | CB | LEU | B | 348 | 38.890 | 68.601 | 29.388 | 1.00 | 31.11 | B | C |
| ATOM | 1946 | CG | LEU | B | 348 | 39.210 | 67.480 | 30.384 | 1.00 | 31.27 | B | C |
| ATOM | 1947 | CD1 | LEU | B | 348 | 39.532 | 68.092 | 31.739 | 1.00 | 31.09 | B | C |
| ATOM | 1948 | CD2 | LEU | B | 348 | 38.032 | 66.514 | 30.495 | 1.00 | 29.33 | B | C |
| ATOM | 1949 | C | LEU | B | 348 | 38.167 | 69.268 | 27.091 | 1.00 | 32.90 | B | C |
| ATOM | 1950 | O | LEU | B | 348 | 36.955 | 69.446 | 27.198 | 1.00 | 33.74 | B | O |
| ATOM | 1951 | N | LYS | B | 349 | 38.936 | 69.982 | 26.278 | 1.00 | 33.03 | B | N |
| ATOM | 1952 | CA | LYS | B | 349 | 38.397 | 71.033 | 25.421 | 1.00 | 35.43 | B | C |
| ATOM | 1953 | CB | LYS | B | 349 | 37.205 | 70.491 | 24.619 | 1.00 | 40.99 | B | C |
| ATOM | 1954 | CG | LYS | B | 349 | 36.533 | 71.506 | 23.689 | 1.00 | 49.49 | B | C |
| ATOM | 1955 | CD | LYS | B | 349 | 35.087 | 71.801 | 24.113 | 1.00 | 51.78 | B | C |
| ATOM | 1956 | CE | LYS | B | 349 | 34.790 | 73.302 | 24.084 | 1.00 | 54.49 | B | C |
| ATOM | 1957 | NZ | LYS | B | 349 | 35.382 | 73.987 | 22.889 | 1.00 | 53.90 | B | N |
| ATOM | 1958 | C | LYS | B | 349 | 37.977 | 72.272 | 26.212 | 1.00 | 34.69 | B | C |
| ATOM | 1959 | O | LYS | B | 349 | 36.887 | 72.811 | 26.014 | 1.00 | 34.39 | B | O |
| ATOM | 1960 | N | LEU | B | 350 | 38.844 | 72.731 | 27.108 | 1.00 | 31.81 | B | N |
| ATOM | 1961 | CA | LEU | B | 350 | 38.526 | 73.912 | 27.896 | 1.00 | 29.11 | B | C |
| ATOM | 1962 | CB | LEU | B | 350 | 37.819 | 73.528 | 29.204 | 1.00 | 28.43 | B | C |
| ATOM | 1963 | CG | LEU | B | 350 | 37.077 | 72.199 | 29.343 | 1.00 | 30.55 | B | C |
| ATOM | 1964 | CD1 | LEU | B | 350 | 37.343 | 71.609 | 30.721 | 1.00 | 29.70 | B | C |
| ATOM | 1965 | CD2 | LEU | B | 350 | 35.588 | 72.421 | 29.137 | 1.00 | 28.04 | B | C |
| ATOM | 1966 | C | LEU | B | 350 | 39.751 | 74.722 | 28.252 | 1.00 | 28.84 | B | C |
| ATOM | 1967 | O | LEU | B | 350 | 40.862 | 74.199 | 28.300 | 1.00 | 28.52 | B | O |
| ATOM | 1968 | N | HIS | B | 351 | 39.545 | 76.013 | 28.477 | 1.00 | 30.88 | B | N |
| ATOM | 1969 | CA | HIS | B | 351 | 40.627 | 76.871 | 28.914 | 1.00 | 32.08 | B | C |
| ATOM | 1970 | CB | HIS | B | 351 | 40.923 | 78.003 | 27.937 | 1.00 | 34.60 | B | C |
| ATOM | 1971 | CG | HIS | B | 351 | 42.156 | 78.774 | 28.297 | 1.00 | 40.29 | B | C |
| ATOM | 1972 | CD2 | HIS | B | 351 | 42.374 | 79.709 | 29.254 | 1.00 | 41.63 | B | C |
| ATOM | 1973 | ND1 | HIS | B | 351 | 43.376 | 78.557 | 27.693 | 1.00 | 41.56 | B | N |
| ATOM | 1974 | CE1 | HIS | B | 351 | 44.292 | 79.320 | 28.264 | 1.00 | 42.95 | B | C |
| ATOM | 1975 | NE2 | HIS | B | 351 | 43.710 | 80.029 | 29.214 | 1.00 | 42.67 | B | N |
| ATOM | 1976 | C | HIS | B | 351 | 40.176 | 77.461 | 30.242 | 1.00 | 31.93 | B | C |
| ATOM | 1977 | O | HIS | B | 351 | 39.221 | 78.239 | 30.302 | 1.00 | 30.28 | B | O |
| ATOM | 1978 | N | PRO | B | 352 | 40.848 | 77.075 | 31.331 | 1.00 | 31.07 | B | N |
| ATOM | 1979 | CD | PRO | B | 352 | 41.966 | 76.124 | 31.356 | 1.00 | 31.15 | B | C |
| ATOM | 1980 | CA | PRO | B | 352 | 40.523 | 77.559 | 32.671 | 1.00 | 31.52 | B | C |
| ATOM | 1981 | CB | PRO | B | 352 | 41.814 | 77.341 | 33.461 | 1.00 | 31.07 | B | C |
| ATOM | 1982 | CG | PRO | B | 352 | 42.735 | 76.551 | 32.557 | 1.00 | 29.81 | B | C |
| ATOM | 1983 | C | PRO | B | 352 | 40.041 | 79.010 | 32.747 | 1.00 | 31.36 | B | C |
| ATOM | 1984 | O | PRO | B | 352 | 39.028 | 79.291 | 33.387 | 1.00 | 33.31 | B | O |
| ATOM | 1985 | N | TYR | B | 353 | 40.748 | 79.921 | 32.085 | 1.00 | 28.99 | B | N |
| ATOM | 1986 | CA | TYR | B | 353 | 40.392 | 81.336 | 32.132 | 1.00 | 28.96 | B | C |
| ATOM | 1987 | CB | TYR | B | 353 | 41.461 | 82.164 | 31.416 | 1.00 | 31.12 | B | C |
| ATOM | 1988 | CG | TYR | B | 353 | 42.822 | 82.067 | 32.073 | 1.00 | 34.44 | B | C |
| ATOM | 1989 | CD1 | TYR | B | 353 | 42.978 | 81.442 | 33.316 | 1.00 | 35.30 | B | C |
| ATOM | 1990 | CE1 | TYR | B | 353 | 44.233 | 81.325 | 33.918 | 1.00 | 35.80 | B | C |
| ATOM | 1991 | CD2 | TYR | B | 353 | 43.961 | 82.577 | 31.445 | 1.00 | 36.77 | B | C |
| ATOM | 1992 | CE2 | TYR | B | 353 | 45.229 | 82.466 | 32.040 | 1.00 | 37.52 | B | C |
| ATOM | 1993 | CZ | TYR | B | 353 | 45.355 | 81.838 | 33.275 | 1.00 | 37.46 | B | C |
| ATOM | 1994 | OH | TYR | B | 353 | 46.597 | 81.717 | 33.863 | 1.00 | 35.24 | B | O |
| ATOM | 1995 | C | TYR | B | 353 | 39.006 | 81.705 | 31.612 | 1.00 | 27.04 | B | C |
| ATOM | 1996 | O | TYR | B | 353 | 38.497 | 82.781 | 31.919 | 1.00 | 25.47 | B | O |
| ATOM | 1997 | N | ASP | B | 354 | 38.393 | 80.819 | 30.836 | 1.00 | 26.54 | B | N |
| ATOM | 1998 | CA | ASP | B | 354 | 37.052 | 81.070 | 30.308 | 1.00 | 25.68 | B | C |
| ATOM | 1999 | CB | ASP | B | 354 | 36.885 | 80.450 | 28.918 | 1.00 | 28.50 | B | C |
| ATOM | 2000 | CG | ASP | B | 354 | 37.805 | 81.067 | 27.890 | 1.00 | 33.34 | B | C |
| ATOM | 2001 | OD1 | ASP | B | 354 | 37.969 | 82.307 | 27.904 | 1.00 | 35.31 | B | O |
| ATOM | 2002 | OD2 | ASP | B | 354 | 38.364 | 80.308 | 27.068 | 1.00 | 33.56 | B | O |
| ATOM | 2003 | C | ASP | B | 354 | 36.011 | 80.472 | 31.239 | 1.00 | 22.26 | B | C |
| ATOM | 2004 | O | ASP | B | 354 | 34.812 | 80.677 | 31.059 | 1.00 | 22.00 | B | O |
| ATOM | 2005 | N | LEU | B | 355 | 36.478 | 79.721 | 32.231 | 1.00 | 21.14 | B | N |
| ATOM | 2006 | CA | LEU | B | 355 | 35.585 | 79.088 | 33.186 | 1.00 | 20.93 | B | C |
| ATOM | 2007 | CB | LEU | B | 355 | 36.371 | 78.199 | 34.143 | 1.00 | 18.64 | B | C |
| ATOM | 2008 | CG | LEU | B | 355 | 36.741 | 76.850 | 33.516 | 1.00 | 18.90 | B | C |
| ATOM | 2009 | CD1 | LEU | B | 355 | 37.381 | 75.969 | 34.562 | 1.00 | 18.91 | B | C |
| ATOM | 2010 | CD2 | LEU | B | 355 | 35.500 | 76.178 | 32.936 | 1.00 | 17.44 | B | C |
| ATOM | 2011 | C | LEU | B | 355 | 34.765 | 80.109 | 33.954 | 1.00 | 21.05 | B | C |
| ATOM | 2012 | O | LEU | B | 355 | 35.180 | 81.256 | 34.153 | 1.00 | 18.54 | B | O |
| ATOM | 2013 | N | THR | B | 356 | 33.594 | 79.664 | 34.385 | 1.00 | 20.20 | B | N |
| ATOM | 2014 | CA | THR | B | 356 | 32.632 | 80.496 | 35.090 | 1.00 | 21.27 | B | C |
| ATOM | 2015 | CB | THR | B | 356 | 31.630 | 81.012 | 34.042 | 1.00 | 18.45 | B | C |
| ATOM | 2016 | OG1 | THR | B | 356 | 32.071 | 82.279 | 33.550 | 1.00 | 19.58 | B | O |
| ATOM | 2017 | CG2 | THR | B | 356 | 30.254 | 81.123 | 34.599 | 1.00 | 21.65 | B | C |
| ATOM | 2018 | C | THR | B | 356 | 31.939 | 79.587 | 36.115 | 1.00 | 21.87 | B | C |
| ATOM | 2019 | O | THR | B | 356 | 32.110 | 78.370 | 36.047 | 1.00 | 24.82 | B | O |
| ATOM | 2020 | N | VAL | B | 357 | 31.184 | 80.127 | 37.072 | 1.00 | 20.00 | B | N |
| ATOM | 2021 | CA | VAL | B | 357 | 30.507 | 79.206 | 37.989 | 1.00 | 19.86 | B | C |
| ATOM | 2022 | CB | VAL | B | 357 | 29.844 | 79.909 | 39.227 | 1.00 | 19.50 | B | C |
| ATOM | 2023 | CG1 | VAL | B | 357 | 30.838 | 80.856 | 39.890 | 1.00 | 15.25 | B | C |
| ATOM | 2024 | CG2 | VAL | B | 357 | 28.570 | 80.616 | 38.828 | 1.00 | 17.04 | B | C |
| ATOM | 2025 | C | VAL | B | 357 | 29.441 | 78.458 | 37.180 | 1.00 | 19.85 | B | C |
| ATOM | 2026 | O | VAL | B | 357 | 29.074 | 77.335 | 37.516 | 1.00 | 19.97 | B | O |
| ATOM | 2027 | N | ASP | B | 358 | 28.967 | 79.074 | 36.098 | 1.00 | 18.05 | B | N |
| ATOM | 2028 | CA | ASP | B | 358 | 27.974 | 78.443 | 35.230 | 1.00 | 18.69 | B | C |
| ATOM | 2029 | CB | ASP | B | 358 | 27.511 | 79.406 | 34.134 | 1.00 | 20.35 | B | C |
| ATOM | 2030 | CG | ASP | B | 358 | 26.651 | 80.534 | 34.660 | 1.00 | 23.05 | B | C |
| ATOM | 2031 | OD1 | ASP | B | 358 | 25.996 | 80.359 | 35.715 | 1.00 | 26.94 | B | O |
| ATOM | 2032 | OD2 | ASP | B | 358 | 26.626 | 81.601 | 34.003 | 1.00 | 26.36 | B | O |
| ATOM | 2033 | C | ASP | B | 358 | 28.577 | 77.210 | 34.555 | 1.00 | 17.83 | B | C |
| ATOM | 2034 | O | ASP | B | 358 | 27.970 | 76.144 | 34.544 | 1.00 | 20.42 | B | O |
| ATOM | 2035 | N | SER | B | 359 | 29.767 | 77.365 | 33.982 | 1.00 | 17.44 | B | N |
| ATOM | 2036 | CA | SER | B | 359 | 30.448 | 76.263 | 33.305 | 1.00 | 16.21 | B | C |
| ATOM | 2037 | CB | SER | B | 359 | 31.552 | 76.795 | 32.382 | 1.00 | 13.41 | B | C |
| ATOM | 2038 | OG | SER | B | 359 | 32.311 | 77.809 | 33.006 | 1.00 | 14.77 | B | O |
| ATOM | 2039 | C | SER | B | 359 | 31.036 | 75.265 | 34.292 | 1.00 | 15.80 | B | C |
| ATOM | 2040 | O | SER | B | 359 | 31.188 | 74.086 | 33.973 | 1.00 | 16.15 | B | O |
| ATOM | 2041 | N | LEU | B | 360 | 31.372 | 75.742 | 35.487 | 1.00 | 16.77 | B | N |
| ATOM | 2042 | CA | LEU | B | 360 | 31.918 | 74.874 | 36.532 | 1.00 | 17.35 | B | C |
| ATOM | 2043 | CB | LEU | B | 360 | 32.357 | 75.707 | 37.732 | 1.00 | 16.86 | B | C |
| ATOM | 2044 | CG | LEU | B | 360 | 32.901 | 74.909 | 38.912 | 1.00 | 18.77 | B | C |
| ATOM | 2045 | CD1 | LEU | B | 360 | 34.144 | 74.132 | 38.492 | 1.00 | 17.88 | B | C |
| ATOM | 2046 | CD2 | LEU | B | 360 | 33.212 | 75.863 | 40.055 | 1.00 | 19.03 | B | C |
| ATOM | 2047 | C | LEU | B | 360 | 30.844 | 73.868 | 36.955 | 1.00 | 15.77 | B | C |
| ATOM | 2048 | O | LEU | B | 360 | 31.152 | 72.740 | 37.324 | 1.00 | 15.04 | B | O |
| ATOM | 2049 | N | ASP | B | 361 | 29.588 | 74.306 | 36.901 | 1.00 | 17.47 | B | N |
| ATOM | 2050 | CA | ASP | B | 361 | 28.418 | 73.486 | 37.213 | 1.00 | 21.07 | B | C |
| ATOM | 2051 | CB | ASP | B | 361 | 28.063 | 72.638 | 35.978 | 1.00 | 22.89 | B | C |
| ATOM | 2052 | CG | ASP | B | 361 | 26.565 | 72.462 | 35.789 | 1.00 | 27.76 | B | C |
| ATOM | 2053 | OD1 | ASP | B | 361 | 25.781 | 73.235 | 36.387 | 1.00 | 33.88 | B | O |
| ATOM | 2054 | OD2 | ASP | B | 361 | 26.173 | 71.545 | 35.038 | 1.00 | 29.50 | B | O |
| ATOM | 2055 | C | ASP | B | 361 | 28.502 | 72.577 | 38.450 | 1.00 | 22.54 | B | C |
| ATOM | 2056 | O | ASP | B | 361 | 28.111 | 71.411 | 38.383 | 1.00 | 21.77 | B | O |
| ATOM | 2057 | N | VAL | B | 362 | 28.981 | 73.097 | 39.579 | 1.00 | 23.59 | B | N |
| ATOM | 2058 | CA | VAL | B | 362 | 29.073 | 72.279 | 40.786 | 1.00 | 23.21 | B | C |
| ATOM | 2059 | CB | VAL | B | 362 | 30.387 | 72.530 | 41.553 | 1.00 | 20.22 | B | C |
| ATOM | 2060 | CG1 | VAL | B | 362 | 31.525 | 71.809 | 40.857 | 1.00 | 17.95 | B | C |
| ATOM | 2061 | CG2 | VAL | B | 362 | 30.671 | 74.015 | 41.643 | 1.00 | 21.53 | B | C |
| ATOM | 2062 | C | VAL | B | 362 | 27.895 | 72.506 | 41.731 | 1.00 | 26.32 | B | C |
| ATOM | 2063 | O | VAL | B | 362 | 27.690 | 71.740 | 42.675 | 1.00 | 26.16 | B | O |
| ATOM | 2064 | N | HIS | B | 363 | 27.118 | 73.553 | 41.468 | 1.00 | 27.59 | B | N |
| ATOM | 2065 | CA | HIS | B | 363 | 25.963 | 73.885 | 42.292 | 1.00 | 27.92 | B | C |
| ATOM | 2066 | CB | HIS | B | 363 | 25.580 | 75.345 | 42.079 | 1.00 | 26.27 | B | C |
| ATOM | 2067 | CG | HIS | B | 363 | 24.972 | 75.997 | 43.278 | 1.00 | 30.60 | B | C |
| ATOM | 2068 | CD2 | HIS | B | 363 | 25.542 | 76.532 | 44.384 | 1.00 | 28.01 | B | C |
| ATOM | 2069 | ND1 | HIS | B | 363 | 23.611 | 76.182 | 43.415 | 1.00 | 30.18 | B | N |
| ATOM | 2070 | CE1 | HIS | B | 363 | 23.368 | 76.803 | 44.555 | 1.00 | 30.38 | B | C |
| ATOM | 2071 | NE2 | HIS | B | 363 | 24.523 | 77.026 | 45.160 | 1.00 | 31.32 | B | N |
| ATOM | 2072 | C | HIS | B | 363 | 24.777 | 73.003 | 41.936 | 1.00 | 29.43 | B | C |
| ATOM | 2073 | O | HIS | B | 363 | 24.498 | 72.771 | 40.757 | 1.00 | 32.38 | B | O |
| ATOM | 2074 | N | ALA | B | 364 | 24.090 | 72.499 | 42.954 | 1.00 | 31.37 | B | N |
| ATOM | 2075 | CA | ALA | B | 364 | 22.925 | 71.643 | 42.748 | 1.00 | 33.21 | B | C |
| ATOM | 2076 | CB | ALA | B | 364 | 22.573 | 70.913 | 44.036 | 1.00 | 34.84 | B | C |
| ATOM | 2077 | C | ALA | B | 364 | 21.762 | 72.510 | 42.305 | 1.00 | 34.97 | B | C |
| ATOM | 2078 | O | ALA | B | 364 | 21.482 | 73.544 | 42.912 | 1.00 | 37.95 | B | O |
| ATOM | 2079 | N | GLY | B | 365 | 21.066 | 72.091 | 41.255 | 1.00 | 38.07 | B | N |
| ATOM | 2080 | CA | GLY | B | 365 | 19.961 | 72.903 | 40.762 | 1.00 | 39.66 | B | C |
| ATOM | 2081 | C | GLY | B | 365 | 18.632 | 72.414 | 41.288 | 1.00 | 40.11 | B | C |
| ATOM | 2082 | O | GLY | B | 365 | 18.552 | 72.043 | 42.451 | 1.00 | 43.49 | B | O |
| ATOM | 2083 | N | ARG | B | 366 | 17.581 | 72.447 | 40.450 | 1.00 | 39.84 | B | N |
| ATOM | 2084 | CA | ARG | B | 366 | 16.261 | 71.953 | 40.843 | 1.00 | 38.32 | B | C |
| ATOM | 2085 | CB | ARG | B | 366 | 15.150 | 72.477 | 39.939 | 1.00 | 37.77 | B | C |
| ATOM | 2086 | CG | ARG | B | 366 | 15.425 | 73.806 | 39.349 | 1.00 | 35.84 | B | C |
| ATOM | 2087 | CD | ARG | B | 366 | 14.394 | 74.787 | 39.840 | 1.00 | 34.71 | B | C |
| ATOM | 2088 | NE | ARG | B | 366 | 14.402 | 75.941 | 38.957 | 1.00 | 36.93 | B | N |
| ATOM | 2089 | CZ | ARG | B | 366 | 13.972 | 75.911 | 37.699 | 1.00 | 36.48 | B | C |
| ATOM | 2090 | NH1 | ARG | B | 366 | 13.490 | 74.782 | 37.180 | 1.00 | 36.57 | B | N |
| ATOM | 2091 | NH2 | ARG | B | 366 | 14.048 | 77.007 | 36.955 | 1.00 | 39.51 | B | N |
| ATOM | 2092 | C | ARG | B | 366 | 16.327 | 70.447 | 40.690 | 1.00 | 38.88 | B | C |
| ATOM | 2093 | O | ARG | B | 366 | 15.630 | 69.701 | 41.385 | 1.00 | 41.48 | B | O |
| ATOM | 2094 | N | GLN | B | 367 | 17.163 | 70.011 | 39.755 | 1.00 | 39.00 | B | N |
| ATOM | 2095 | CA | GLN | B | 367 | 17.373 | 68.586 | 39.490 | 1.00 | 41.90 | B | C |
| ATOM | 2096 | CB | GLN | B | 367 | 18.069 | 68.393 | 38.126 | 1.00 | 42.41 | B | C |
| ATOM | 2097 | CG | GLN | B | 367 | 19.326 | 67.506 | 38.121 | 1.00 | 45.87 | B | C |
| ATOM | 2098 | CD | GLN | B | 367 | 20.615 | 68.316 | 37.917 | 1.00 | 49.64 | B | C |
| ATOM | 2099 | OE1 | GLN | B | 367 | 20.582 | 69.464 | 37.461 | 1.00 | 54.18 | B | O |
| ATOM | 2100 | NE2 | GLN | B | 367 | 21.755 | 67.719 | 38.268 | 1.00 | 49.44 | B | N |
| ATOM | 2101 | C | GLN | B | 367 | 18.232 | 68.068 | 40.637 | 1.00 | 41.35 | B | C |
| ATOM | 2102 | O | GLN | B | 367 | 18.488 | 68.820 | 41.584 | 1.00 | 42.78 | B | O |
| ATOM | 2103 | N | THR | B | 368 | 18.687 | 66.813 | 40.573 | 1.00 | 38.94 | B | N |
| ATOM | 2104 | CA | THR | B | 368 | 19.487 | 66.231 | 41.658 | 1.00 | 36.85 | B | C |
| ATOM | 2105 | CB | THR | B | 368 | 20.660 | 67.158 | 42.166 | 1.00 | 36.95 | B | C |
| ATOM | 2106 | OG1 | THR | B | 368 | 20.152 | 68.120 | 43.113 | 1.00 | 35.93 | B | O |
| ATOM | 2107 | CG2 | THR | B | 368 | 21.362 | 67.881 | 40.983 | 1.00 | 37.86 | B | C |
| ATOM | 2108 | C | THR | B | 368 | 18.551 | 66.003 | 42.846 | 1.00 | 33.83 | B | C |
| ATOM | 2109 | O | THR | B | 368 | 18.828 | 65.182 | 43.735 | 1.00 | 34.20 | B | O |
| ATOM | 2110 | N | PHE | B | 369 | 17.459 | 66.761 | 42.866 | 1.00 | 33.01 | B | N |
| ATOM | 2111 | CA | PHE | B | 369 | 16.450 | 66.644 | 43.904 | 1.00 | 30.75 | B | C |
| ATOM | 2112 | CB | PHE | B | 369 | 15.355 | 67.695 | 43.697 | 1.00 | 30.27 | B | C |
| ATOM | 2113 | CG | PHE | B | 369 | 14.266 | 67.620 | 44.717 | 1.00 | 31.59 | B | C |
| ATOM | 2114 | CD1 | PHE | B | 369 | 14.441 | 68.171 | 45.986 | 1.00 | 30.22 | B | C |
| ATOM | 2115 | CD2 | PHE | B | 369 | 13.091 | 66.923 | 44.438 | 1.00 | 29.98 | B | C |
| ATOM | 2116 | CE1 | PHE | B | 369 | 13.460 | 68.020 | 46.967 | 1.00 | 28.60 | B | C |
| ATOM | 2117 | CE2 | PHE | B | 369 | 12.109 | 66.770 | 45.413 | 1.00 | 27.70 | B | C |
| ATOM | 2118 | CZ | PHE | B | 369 | 12.291 | 67.317 | 46.674 | 1.00 | 26.21 | B | C |
| ATOM | 2119 | C | PHE | B | 369 | 15.893 | 65.245 | 43.738 | 1.00 | 30.64 | B | C |
| ATOM | 2120 | O | PHE | B | 369 | 15.255 | 64.951 | 42.723 | 1.00 | 29.31 | B | O |
| ATOM | 2121 | N | GLN | B | 370 | 16.149 | 64.386 | 44.721 | 1.00 | 31.91 | B | N |
| ATOM | 2122 | CA | GLN | B | 370 | 15.707 | 62.996 | 44.654 | 1.00 | 30.70 | B | C |
| ATOM | 2123 | CB | GLN | B | 370 | 14.179 | 62.912 | 44.643 | 1.00 | 30.12 | B | C |
| ATOM | 2124 | CG | GLN | B | 370 | 13.627 | 62.741 | 46.048 | 1.00 | 31.63 | B | C |
| ATOM | 2125 | CD | GLN | B | 370 | 12.161 | 63.094 | 46.154 | 1.00 | 33.75 | B | C |
| ATOM | 2126 | OE1 | GLN | B | 370 | 11.633 | 63.879 | 45.354 | 1.00 | 37.09 | B | O |
| ATOM | 2127 | NE2 | GLN | B | 370 | 11.491 | 62.520 | 47.144 | 1.00 | 32.84 | B | N |
| ATOM | 2128 | C | GLN | B | 370 | 16.321 | 62.360 | 43.408 | 1.00 | 30.08 | B | C |
| ATOM | 2129 | O | GLN | B | 370 | 15.704 | 61.535 | 42.730 | 1.00 | 28.08 | B | O |
| ATOM | 2130 | N | ARG | B | 371 | 17.543 | 62.794 | 43.104 | 1.00 | 27.69 | B | N |
| ATOM | 2131 | CA | ARG | B | 371 | 18.331 | 62.261 | 41.996 | 1.00 | 26.62 | B | C |
| ATOM | 2132 | CB | ARG | B | 371 | 18.361 | 63.217 | 40.784 | 1.00 | 26.33 | B | C |
| ATOM | 2133 | CG | ARG | B | 371 | 17.040 | 63.329 | 39.991 | 1.00 | 27.44 | B | C |
| ATOM | 2134 | CD | ARG | B | 371 | 16.807 | 62.212 | 38.958 | 1.00 | 28.58 | B | C |
| ATOM | 2135 | NE | ARG | B | 371 | 18.020 | 61.514 | 38.513 | 1.00 | 32.78 | B | N |
| ATOM | 2136 | CZ | ARG | B | 371 | 18.570 | 61.653 | 37.299 | 1.00 | 34.84 | B | C |
| ATOM | 2137 | NH1 | ARG | B | 371 | 18.023 | 62.474 | 36.404 | 1.00 | 35.64 | B | N |
| ATOM | 2138 | NH2 | ARG | B | 371 | 19.646 | 60.942 | 36.957 | 1.00 | 30.55 | B | N |
| ATOM | 2139 | C | ARG | B | 371 | 19.706 | 62.196 | 42.636 | 1.00 | 26.42 | B | C |
| ATOM | 2140 | O | ARG | B | 371 | 20.558 | 63.040 | 42.380 | 1.00 | 25.18 | B | O |
| ATOM | 2141 | N | PHE | B | 372 | 19.912 | 61.210 | 43.508 | 1.00 | 28.12 | B | N |
| ATOM | 2142 | CA | PHE | B | 372 | 21.209 | 61.112 | 44.174 | 1.00 | 29.23 | B | C |
| ATOM | 2143 | CB | PHE | B | 372 | 21.246 | 59.944 | 45.159 | 1.00 | 27.73 | B | C |
| ATOM | 2144 | CG | PHE | B | 372 | 22.223 | 60.153 | 46.290 | 1.00 | 26.94 | B | C |
| ATOM | 2145 | CD1 | PHE | B | 372 | 21.858 | 60.904 | 47.411 | 1.00 | 25.51 | B | C |
| ATOM | 2146 | CD2 | PHE | B | 372 | 23.509 | 59.627 | 46.226 | 1.00 | 24.76 | B | C |
| ATOM | 2147 | CE1 | PHE | B | 372 | 22.764 | 61.130 | 48.447 | 1.00 | 22.21 | B | C |
| ATOM | 2148 | CE2 | PHE | B | 372 | 24.420 | 59.846 | 47.249 | 1.00 | 25.95 | B | C |
| ATOM | 2149 | CZ | PHE | B | 372 | 24.048 | 60.603 | 48.365 | 1.00 | 23.18 | B | C |
| ATOM | 2150 | C | PHE | B | 372 | 22.310 | 60.955 | 43.147 | 1.00 | 30.14 | B | C |
| ATOM | 2151 | O | PHE | B | 372 | 23.383 | 61.539 | 43.274 | 1.00 | 30.69 | B | O |
| ATOM | 2152 | N | ASP | B | 373 | 22.035 | 60.158 | 42.122 | 1.00 | 29.67 | B | N |
| ATOM | 2153 | CA | ASP | B | 373 | 22.976 | 59.917 | 41.036 | 1.00 | 31.76 | B | C |
| ATOM | 2154 | CB | ASP | B | 373 | 22.233 | 59.224 | 39.906 | 1.00 | 34.08 | B | C |
| ATOM | 2155 | CG | ASP | B | 373 | 20.949 | 59.948 | 39.569 | 1.00 | 39.38 | B | C |
| ATOM | 2156 | OD1 | ASP | B | 373 | 21.028 | 60.926 | 38.782 | 1.00 | 44.18 | B | O |
| ATOM | 2157 | OD2 | ASP | B | 373 | 19.880 | 59.567 | 40.110 | 1.00 | 41.17 | B | O |
| ATOM | 2158 | C | ASP | B | 373 | 23.543 | 61.252 | 40.523 | 1.00 | 31.08 | B | C |
| ATOM | 2159 | O | ASP | B | 373 | 24.756 | 61.389 | 40.297 | 1.00 | 28.33 | B | O |
| ATOM | 2160 | N | LYS | B | 374 | 22.655 | 62.229 | 40.332 | 1.00 | 28.09 | B | N |
| ATOM | 2161 | CA | LYS | B | 374 | 23.056 | 63.549 | 39.834 | 1.00 | 29.64 | B | C |
| ATOM | 2162 | CB | LYS | B | 374 | 21.835 | 64.347 | 39.366 | 1.00 | 33.08 | B | C |
| ATOM | 2163 | CG | LYS | B | 374 | 21.274 | 63.899 | 38.017 | 1.00 | 36.20 | B | C |
| ATOM | 2164 | CD | LYS | B | 374 | 21.063 | 65.086 | 37.079 | 1.00 | 37.59 | B | C |
| ATOM | 2165 | CE | LYS | B | 374 | 20.555 | 64.623 | 35.724 | 1.00 | 40.10 | B | C |
| ATOM | 2166 | NZ | LYS | B | 374 | 19.232 | 65.248 | 35.391 | 1.00 | 43.55 | B | N |
| ATOM | 2167 | C | LYS | B | 374 | 23.785 | 64.345 | 40.907 | 1.00 | 29.14 | B | C |
| ATOM | 2168 | O | LYS | B | 374 | 24.621 | 65.202 | 40.604 | 1.00 | 29.30 | B | O |
| ATOM | 2169 | N | PHE | B | 375 | 23.457 | 64.069 | 42.166 | 1.00 | 29.02 | B | N |
| ATOM | 2170 | CA | PHE | B | 375 | 24.104 | 64.761 | 43.268 | 1.00 | 26.50 | B | C |
| ATOM | 2171 | CB | PHE | B | 375 | 23.429 | 64.407 | 44.597 | 1.00 | 25.76 | B | C |
| ATOM | 2172 | CG | PHE | B | 375 | 24.279 | 64.711 | 45.794 | 1.00 | 24.59 | B | C |
| ATOM | 2173 | CD1 | PHE | B | 375 | 24.566 | 66.028 | 46.135 | 1.00 | 24.59 | B | C |
| ATOM | 2174 | CD2 | PHE | B | 375 | 24.860 | 63.683 | 46.529 | 1.00 | 23.84 | B | C |
| ATOM | 2175 | CE1 | PHE | B | 375 | 25.430 | 66.326 | 47.184 | 1.00 | 24.25 | B | C |
| ATOM | 2176 | CE2 | PHE | B | 375 | 25.725 | 63.966 | 47.581 | 1.00 | 22.69 | B | C |
| ATOM | 2177 | CZ | PHE | B | 375 | 26.015 | 65.292 | 47.908 | 1.00 | 24.87 | B | C |
| ATOM | 2178 | C | PHE | B | 375 | 25.584 | 64.374 | 43.326 | 1.00 | 25.19 | B | C |
| ATOM | 2179 | O | PHE | B | 375 | 26.459 | 65.236 | 43.413 | 1.00 | 22.77 | B | O |
| ATOM | 2180 | N | ASN | B | 376 | 25.859 | 63.073 | 43.277 | 1.00 | 26.59 | B | N |
| ATOM | 2181 | CA | ASN | B | 376 | 27.240 | 62.588 | 43.330 | 1.00 | 29.51 | B | C |
| ATOM | 2182 | CB | ASN | B | 376 | 27.275 | 61.057 | 43.470 | 1.00 | 31.18 | B | C |
| ATOM | 2183 | CG | ASN | B | 376 | 27.785 | 60.600 | 44.841 | 1.00 | 35.07 | B | C |
| ATOM | 2184 | OD1 | ASN | B | 376 | 28.944 | 60.851 | 45.215 | 1.00 | 39.60 | B | O |
| ATOM | 2185 | ND2 | ASN | B | 376 | 26.924 | 59.926 | 45.595 | 1.00 | 32.58 | B | N |
| ATOM | 2186 | C | ASN | B | 376 | 28.031 | 63.001 | 42.089 | 1.00 | 32.05 | B | C |
| ATOM | 2187 | O | ASN | B | 376 | 29.258 | 63.112 | 42.128 | 1.00 | 31.60 | B | O |
| ATOM | 2188 | N | ASP | B | 377 | 27.332 | 63.239 | 40.981 | 1.00 | 34.12 | B | N |
| ATOM | 2189 | CA | ASP | B | 377 | 28.034 | 63.625 | 39.770 | 1.00 | 38.00 | B | C |
| ATOM | 2190 | CB | ASP | B | 377 | 27.284 | 63.106 | 38.534 | 1.00 | 38.71 | B | C |
| ATOM | 2191 | CG | ASP | B | 377 | 27.935 | 61.842 | 37.975 | 1.00 | 42.90 | B | C |
| ATOM | 2192 | OD1 | ASP | B | 377 | 28.553 | 61.091 | 38.774 | 1.00 | 43.54 | B | O |
| ATOM | 2193 | OD2 | ASP | B | 377 | 27.845 | 61.587 | 36.753 | 1.00 | 45.91 | B | O |
| ATOM | 2194 | C | ASP | B | 377 | 28.270 | 65.124 | 39.720 | 1.00 | 41.90 | B | C |
| ATOM | 2195 | O | ASP | B | 377 | 28.896 | 65.655 | 38.796 | 1.00 | 42.60 | B | O |
| ATOM | 2196 | N | LYS | B | 378 | 27.794 | 65.813 | 40.750 | 1.00 | 42.97 | B | N |
| ATOM | 2197 | CA | LYS | B | 378 | 28.000 | 67.250 | 40.850 | 1.00 | 45.94 | B | C |
| ATOM | 2198 | CB | LYS | B | 378 | 26.990 | 67.857 | 41.834 | 1.00 | 47.37 | B | C |
| ATOM | 2199 | CG | LYS | B | 378 | 26.390 | 69.186 | 41.388 | 1.00 | 49.43 | B | C |
| ATOM | 2200 | CD | LYS | B | 378 | 25.233 | 68.981 | 40.414 | 1.00 | 53.07 | B | C |
| ATOM | 2201 | CE | LYS | B | 378 | 25.304 | 69.942 | 39.239 | 1.00 | 52.60 | B | C |
| ATOM | 2202 | NZ | LYS | B | 378 | 23.950 | 70.425 | 38.847 | 1.00 | 59.16 | B | N |
| ATOM | 2203 | C | LYS | B | 378 | 29.431 | 67.504 | 41.335 | 1.00 | 46.80 | B | C |
| ATOM | 2204 | O | LYS | B | 378 | 29.953 | 68.612 | 41.196 | 1.00 | 43.60 | B | O |
| ATOM | 2205 | N | TYR | B | 379 | 30.066 | 66.477 | 41.900 | 1.00 | 46.11 | B | N |
| ATOM | 2206 | CA | TYR | B | 379 | 31.428 | 66.619 | 42.404 | 1.00 | 46.50 | B | C |
| ATOM | 2207 | CB | TYR | B | 379 | 31.802 | 65.439 | 43.328 | 1.00 | 51.01 | B | C |
| ATOM | 2208 | CG | TYR | B | 379 | 31.194 | 65.495 | 44.715 | 1.00 | 56.52 | B | C |
| ATOM | 2209 | CD1 | TYR | B | 379 | 30.370 | 64.467 | 45.179 | 1.00 | 58.85 | B | C |
| ATOM | 2210 | CE1 | TYR | B | 379 | 29.786 | 64.528 | 46.455 | 1.00 | 60.43 | B | C |
| ATOM | 2211 | CD2 | TYR | B | 379 | 31.421 | 66.584 | 45.554 | 1.00 | 58.29 | B | C |
| ATOM | 2212 | CE2 | TYR | B | 379 | 30.849 | 66.657 | 46.820 | 1.00 | 60.30 | B | C |
| ATOM | 2213 | CZ | TYR | B | 379 | 30.035 | 65.629 | 47.266 | 1.00 | 60.35 | B | C |
| ATOM | 2214 | OH | TYR | B | 379 | 29.500 | 65.717 | 48.529 | 1.00 | 59.90 | B | O |
| ATOM | 2215 | C | TYR | B | 379 | 32.448 | 66.722 | 41.279 | 1.00 | 43.55 | B | C |
| ATOM | 2216 | O | TYR | B | 379 | 33.655 | 66.850 | 41.529 | 1.00 | 43.54 | B | O |
| ATOM | 2217 | N | ASN | B | 380 | 31.958 | 66.664 | 40.043 | 1.00 | 39.17 | B | N |
| ATOM | 2218 | CA | ASN | B | 380 | 32.807 | 66.757 | 38.857 | 1.00 | 33.78 | B | C |
| ATOM | 2219 | CB | ASN | B | 380 | 32.291 | 65.832 | 37.760 | 1.00 | 32.30 | B | C |
| ATOM | 2220 | CG | ASN | B | 380 | 32.272 | 64.384 | 38.191 | 1.00 | 31.78 | B | C |
| ATOM | 2221 | OD1 | ASN | B | 380 | 33.065 | 63.969 | 39.027 | 1.00 | 30.04 | B | O |
| ATOM | 2222 | ND2 | ASN | B | 380 | 31.374 | 63.603 | 37.600 | 1.00 | 29.58 | B | N |
| ATOM | 2223 | C | ASN | B | 380 | 32.818 | 68.185 | 38.334 | 1.00 | 28.14 | B | C |
| ATOM | 2224 | O | ASN | B | 380 | 31.874 | 68.614 | 37.678 | 1.00 | 26.95 | B | O |
| ATOM | 2225 | N | PRO | B | 381 | 33.883 | 68.944 | 38.634 | 1.00 | 23.99 | B | N |
| ATOM | 2226 | CD | PRO | B | 381 | 35.077 | 68.555 | 39.400 | 1.00 | 22.09 | B | C |
| ATOM | 2227 | CA | PRO | B | 381 | 33.961 | 70.326 | 38.157 | 1.00 | 25.37 | B | C |
| ATOM | 2228 | CB | PRO | B | 381 | 35.367 | 70.778 | 38.551 | 1.00 | 23.43 | B | C |
| ATOM | 2229 | CG | PRO | B | 381 | 35.788 | 69.844 | 39.633 | 1.00 | 23.35 | B | C |
| ATOM | 2230 | C | PRO | B | 381 | 33.796 | 70.317 | 36.635 | 1.00 | 26.97 | B | C |
| ATOM | 2231 | O | PRO | B | 381 | 34.354 | 69.450 | 35.957 | 1.00 | 24.04 | B | O |
| ATOM | 2232 | N | VAL | B | 382 | 33.025 | 71.251 | 36.093 | 1.00 | 27.29 | B | N |
| ATOM | 2233 | CA | VAL | B | 382 | 32.807 | 71.327 | 34.649 | 1.00 | 28.82 | B | C |
| ATOM | 2234 | CB | VAL | B | 382 | 34.040 | 71.984 | 33.948 | 1.00 | 29.28 | B | C |
| ATOM | 2235 | CG1 | VAL | B | 382 | 35.078 | 70.950 | 33.619 | 1.00 | 36.03 | B | C |
| ATOM | 2236 | CG2 | VAL | B | 382 | 33.610 | 72.708 | 32.692 | 1.00 | 28.22 | B | C |
| ATOM | 2237 | C | VAL | B | 382 | 32.458 | 69.979 | 33.992 | 1.00 | 28.33 | B | C |
| ATOM | 2238 | O | VAL | B | 382 | 32.760 | 69.739 | 32.823 | 1.00 | 29.01 | B | O |
| ATOM | 2239 | N | GLY | B | 383 | 31.815 | 69.102 | 34.759 | 1.00 | 29.29 | B | N |
| ATOM | 2240 | CA | GLY | B | 383 | 31.395 | 67.806 | 34.245 | 1.00 | 27.41 | B | C |
| ATOM | 2241 | C | GLY | B | 383 | 32.442 | 66.728 | 34.024 | 1.00 | 26.28 | B | C |
| ATOM | 2242 | O | GLY | B | 383 | 32.102 | 65.616 | 33.624 | 1.00 | 26.26 | B | O |
| ATOM | 2243 | N | ALA | B | 384 | 33.706 | 67.037 | 34.288 | 1.00 | 25.45 | B | N |
| ATOM | 2244 | CA | ALA | B | 384 | 34.777 | 66.067 | 34.084 | 1.00 | 21.33 | B | C |
| ATOM | 2245 | CB | ALA | B | 384 | 35.948 | 66.736 | 33.394 | 1.00 | 17.89 | B | C |
| ATOM | 2246 | C | ALA | B | 384 | 35.248 | 65.411 | 35.373 | 1.00 | 20.80 | B | C |
| ATOM | 2247 | O | ALA | B | 384 | 35.632 | 66.092 | 36.316 | 1.00 | 20.55 | B | O |
| ATOM | 2248 | N | SER | B | 385 | 35.227 | 64.082 | 35.399 | 1.00 | 20.05 | B | N |
| ATOM | 2249 | CA | SER | B | 385 | 35.662 | 63.338 | 36.567 | 1.00 | 19.54 | B | C |
| ATOM | 2250 | CB | SER | B | 385 | 35.297 | 61.857 | 36.418 | 1.00 | 18.67 | B | C |
| ATOM | 2251 | OG | SER | B | 385 | 36.089 | 61.221 | 35.429 | 1.00 | 23.96 | B | O |
| ATOM | 2252 | C | SER | B | 385 | 37.166 | 63.487 | 36.752 | 1.00 | 19.49 | B | C |
| ATOM | 2253 | O | SER | B | 385 | 37.677 | 63.384 | 37.862 | 1.00 | 21.92 | B | O |
| ATOM | 2254 | N | GLU | B | 386 | 37.873 | 63.728 | 35.656 | 1.00 | 20.81 | B | N |
| ATOM | 2255 | CA | GLU | B | 386 | 39.321 | 63.891 | 35.703 | 1.00 | 20.78 | B | C |
| ATOM | 2256 | CB | GLU | B | 386 | 39.884 | 64.127 | 34.296 | 1.00 | 21.67 | B | C |
| ATOM | 2257 | CG | GLU | B | 386 | 39.758 | 62.948 | 33.342 | 1.00 | 23.04 | B | C |
| ATOM | 2258 | CD | GLU | B | 386 | 38.480 | 62.991 | 32.516 | 1.00 | 26.51 | B | C |
| ATOM | 2259 | OE1 | GLU | B | 386 | 38.275 | 62.081 | 31.680 | 1.00 | 25.10 | B | O |
| ATOM | 2260 | OE2 | GLU | B | 386 | 37.679 | 63.931 | 32.705 | 1.00 | 25.29 | B | O |
| ATOM | 2261 | C | GLU | B | 386 | 39.664 | 65.085 | 36.580 | 1.00 | 23.01 | B | C |
| ATOM | 2262 | O | GLU | B | 386 | 40.666 | 65.076 | 37.296 | 1.00 | 23.30 | B | O |
| ATOM | 2263 | N | LEU | B | 387 | 38.832 | 66.120 | 36.516 | 1.00 | 22.83 | B | N |
| ATOM | 2264 | CA | LEU | B | 387 | 39.053 | 67.319 | 37.314 | 1.00 | 21.36 | B | C |
| ATOM | 2265 | CB | LEU | B | 387 | 38.190 | 68.457 | 36.791 | 1.00 | 22.32 | B | C |
| ATOM | 2266 | CG | LEU | B | 387 | 38.589 | 68.979 | 35.409 | 1.00 | 23.76 | B | C |
| ATOM | 2267 | CD1 | LEU | B | 387 | 37.732 | 70.177 | 35.056 | 1.00 | 21.87 | B | C |
| ATOM | 2268 | CD2 | LEU | B | 387 | 40.052 | 69.368 | 35.404 | 1.00 | 23.95 | B | C |
| ATOM | 2269 | C | LEU | B | 387 | 38.742 | 67.062 | 38.787 | 1.00 | 21.82 | B | C |
| ATOM | 2270 | O | LEU | B | 387 | 39.380 | 67.622 | 39.673 | 1.00 | 19.37 | B | O |
| ATOM | 2271 | N | ARG | B | 388 | 37.759 | 66.208 | 39.041 | 1.00 | 20.56 | B | N |
| ATOM | 2272 | CA | ARG | B | 388 | 37.394 | 65.864 | 40.404 | 1.00 | 24.41 | B | C |
| ATOM | 2273 | CB | ARG | B | 388 | 36.128 | 65.004 | 40.413 | 1.00 | 27.86 | B | C |
| ATOM | 2274 | CG | ARG | B | 388 | 35.920 | 64.211 | 41.699 | 1.00 | 29.92 | B | C |
| ATOM | 2275 | CD | ARG | B | 388 | 34.450 | 63.958 | 41.912 | 1.00 | 36.60 | B | C |
| ATOM | 2276 | NE | ARG | B | 388 | 34.188 | 63.216 | 43.147 | 1.00 | 43.69 | B | N |
| ATOM | 2277 | CZ | ARG | B | 388 | 33.063 | 62.535 | 43.373 | 1.00 | 47.24 | B | C |
| ATOM | 2278 | NH1 | ARG | B | 388 | 32.102 | 62.500 | 42.454 | 1.00 | 49.72 | B | N |
| ATOM | 2279 | NH2 | ARG | B | 388 | 32.895 | 61.895 | 44.523 | 1.00 | 47.71 | B | N |
| ATOM | 2280 | C | ARG | B | 388 | 38.537 | 65.090 | 41.060 | 1.00 | 24.75 | B | C |
| ATOM | 2281 | O | ARG | B | 388 | 38.891 | 65.345 | 42.209 | 1.00 | 25.27 | B | O |
| ATOM | 2282 | N | ASP | B | 389 | 39.107 | 64.141 | 40.325 | 1.00 | 22.89 | B | N |
| ATOM | 2283 | CA | ASP | B | 389 | 40.204 | 63.327 | 40.833 | 1.00 | 22.65 | B | C |
| ATOM | 2284 | CB | ASP | B | 389 | 40.567 | 62.236 | 39.831 | 1.00 | 23.29 | B | C |
| ATOM | 2285 | CG | ASP | B | 389 | 39.460 | 61.227 | 39.641 | 1.00 | 31.83 | B | C |
| ATOM | 2286 | OD1 | ASP | B | 389 | 39.668 | 60.271 | 38.861 | 1.00 | 34.04 | B | O |
| ATOM | 2287 | OD2 | ASP | B | 389 | 38.383 | 61.386 | 40.264 | 1.00 | 37.24 | B | O |
| ATOM | 2288 | C | ASP | B | 389 | 41.445 | 64.157 | 41.079 | 1.00 | 23.10 | B | C |
| ATOM | 2289 | O | ASP | B | 389 | 42.288 | 63.810 | 41.912 | 1.00 | 22.13 | B | O |
| ATOM | 2290 | N | LEU | B | 390 | 41.566 | 65.250 | 40.335 | 1.00 | 22.10 | B | N |
| ATOM | 2291 | CA | LEU | B | 390 | 42.733 | 66.108 | 40.444 | 1.00 | 18.95 | B | C |
| ATOM | 2292 | CB | LEU | B | 390 | 42.996 | 66.793 | 39.097 | 1.00 | 19.35 | B | C |
| ATOM | 2293 | CG | LEU | B | 390 | 44.078 | 67.883 | 39.044 | 1.00 | 19.79 | B | C |
| ATOM | 2294 | CD1 | LEU | B | 390 | 45.443 | 67.289 | 39.342 | 1.00 | 17.14 | B | C |
| ATOM | 2295 | CD2 | LEU | B | 390 | 44.084 | 68.525 | 37.673 | 1.00 | 17.96 | B | C |
| ATOM | 2296 | C | LEU | B | 390 | 42.642 | 67.153 | 41.540 | 1.00 | 19.78 | B | C |
| ATOM | 2297 | O | LEU | B | 390 | 43.599 | 67.354 | 42.284 | 1.00 | 22.00 | B | O |
| ATOM | 2298 | N | TYR | B | 391 | 41.490 | 67.806 | 41.649 | 1.00 | 19.46 | B | N |
| ATOM | 2299 | CA | TYR | B | 391 | 41.299 | 68.866 | 42.634 | 1.00 | 19.18 | B | C |
| ATOM | 2300 | CB | TYR | B | 391 | 40.547 | 70.035 | 41.981 | 1.00 | 18.70 | B | C |
| ATOM | 2301 | CG | TYR | B | 391 | 41.323 | 70.764 | 40.907 | 1.00 | 16.93 | B | C |
| ATOM | 2302 | CD1 | TYR | B | 391 | 42.301 | 71.702 | 41.241 | 1.00 | 18.07 | B | C |
| ATOM | 2303 | CE1 | TYR | B | 391 | 43.024 | 72.374 | 40.255 | 1.00 | 16.59 | B | C |
| ATOM | 2304 | CD2 | TYR | B | 391 | 41.084 | 70.514 | 39.553 | 1.00 | 17.90 | B | C |
| ATOM | 2305 | CE2 | TYR | B | 391 | 41.804 | 71.181 | 38.558 | 1.00 | 16.33 | B | C |
| ATOM | 2306 | CZ | TYR | B | 391 | 42.771 | 72.106 | 38.918 | 1.00 | 17.61 | B | C |
| ATOM | 2307 | OH | TYR | B | 391 | 43.498 | 72.747 | 37.943 | 1.00 | 15.68 | B | O |
| ATOM | 2308 | C | TYR | B | 391 | 40.572 | 68.496 | 43.934 | 1.00 | 19.42 | B | C |
| ATOM | 2309 | O | TYR | B | 391 | 40.705 | 69.205 | 44.936 | 1.00 | 18.12 | B | O |
| ATOM | 2310 | N | LEU | B | 392 | 39.809 | 67.405 | 43.933 | 1.00 | 17.23 | B | N |
| ATOM | 2311 | CA | LEU | B | 392 | 39.053 | 67.050 | 45.126 | 1.00 | 17.99 | B | C |
| ATOM | 2312 | CB | LEU | B | 392 | 37.562 | 67.262 | 44.868 | 1.00 | 17.10 | B | C |
| ATOM | 2313 | CG | LEU | B | 392 | 37.163 | 68.590 | 44.219 | 1.00 | 16.16 | B | C |
| ATOM | 2314 | CD1 | LEU | B | 392 | 35.711 | 68.533 | 43.796 | 1.00 | 13.15 | B | C |
| ATOM | 2315 | CD2 | LEU | B | 392 | 37.394 | 69.730 | 45.190 | 1.00 | 15.30 | B | C |
| ATOM | 2316 | C | LEU | B | 392 | 39.263 | 65.657 | 45.687 | 1.00 | 18.70 | B | C |
| ATOM | 2317 | O | LEU | B | 392 | 38.374 | 65.115 | 46.343 | 1.00 | 20.06 | B | O |
| ATOM | 2318 | N | LYS | B | 393 | 40.431 | 65.079 | 45.441 | 1.00 | 17.95 | B | N |
| ATOM | 2319 | CA | LYS | B | 393 | 40.731 | 63.749 | 45.949 | 1.00 | 18.62 | B | C |
| ATOM | 2320 | CB | LYS | B | 393 | 40.662 | 62.714 | 44.829 | 1.00 | 19.54 | B | C |
| ATOM | 2321 | CG | LYS | B | 393 | 39.254 | 62.463 | 44.339 | 1.00 | 22.35 | B | C |
| ATOM | 2322 | CD | LYS | B | 393 | 38.972 | 60.989 | 44.206 | 1.00 | 25.59 | B | C |
| ATOM | 2323 | CE | LYS | B | 393 | 37.660 | 60.749 | 43.482 | 1.00 | 27.31 | B | C |
| ATOM | 2324 | NZ | LYS | B | 393 | 37.462 | 59.301 | 43.226 | 1.00 | 33.53 | B | N |
| ATOM | 2325 | C | LYS | B | 393 | 42.110 | 63.752 | 46.574 | 1.00 | 19.79 | B | C |
| ATOM | 2326 | O | LYS | B | 393 | 42.938 | 64.607 | 46.263 | 1.00 | 20.69 | B | O |
| ATOM | 2327 | N | THR | B | 394 | 42.358 | 62.800 | 47.465 | 1.00 | 21.13 | B | N |
| ATOM | 2328 | CA | THR | B | 394 | 43.647 | 62.737 | 48.136 | 1.00 | 20.24 | B | C |
| ATOM | 2329 | CB | THR | B | 394 | 43.480 | 62.296 | 49.626 | 1.00 | 17.10 | B | C |
| ATOM | 2330 | OG1 | THR | B | 394 | 42.940 | 60.974 | 49.694 | 1.00 | 15.51 | B | O |
| ATOM | 2331 | CG2 | THR | B | 394 | 42.544 | 63.243 | 50.350 | 1.00 | 15.19 | B | C |
| ATOM | 2332 | C | THR | B | 394 | 44.639 | 61.827 | 47.422 | 1.00 | 20.13 | B | C |
| ATOM | 2333 | O | THR | B | 394 | 45.851 | 62.011 | 47.532 | 1.00 | 18.25 | B | O |
| ATOM | 2334 | N | ASP | B | 395 | 44.126 | 60.857 | 46.676 | 1.00 | 22.68 | B | N |
| ATOM | 2335 | CA | ASP | B | 395 | 44.993 | 59.937 | 45.958 | 1.00 | 25.94 | B | C |
| ATOM | 2336 | CB | ASP | B | 395 | 44.622 | 58.487 | 46.288 | 1.00 | 29.96 | B | C |
| ATOM | 2337 | CG | ASP | B | 395 | 45.670 | 57.493 | 45.814 | 1.00 | 36.84 | B | C |
| ATOM | 2338 | OD1 | ASP | B | 395 | 46.868 | 57.868 | 45.755 | 1.00 | 39.08 | B | O |
| ATOM | 2339 | OD2 | ASP | B | 395 | 45.298 | 56.335 | 45.503 | 1.00 | 41.03 | B | O |
| ATOM | 2340 | C | ASP | B | 395 | 44.933 | 60.145 | 44.453 | 1.00 | 25.29 | B | C |
| ATOM | 2341 | O | ASP | B | 395 | 43.922 | 59.860 | 43.818 | 1.00 | 27.48 | B | O |
| ATOM | 2342 | N | ASN | B | 396 | 46.020 | 60.652 | 43.886 | 1.00 | 24.72 | B | N |
| ATOM | 2343 | CA | ASN | B | 396 | 46.096 | 60.869 | 42.447 | 1.00 | 22.29 | B | C |
| ATOM | 2344 | CB | ASN | B | 396 | 45.304 | 62.118 | 42.039 | 1.00 | 22.31 | B | C |
| ATOM | 2345 | CG | ASN | B | 396 | 45.859 | 63.392 | 42.639 | 1.00 | 19.29 | B | C |
| ATOM | 2346 | OD1 | ASN | B | 396 | 45.170 | 64.408 | 42.700 | 1.00 | 21.83 | B | O |
| ATOM | 2347 | ND2 | ASN | B | 396 | 47.104 | 63.348 | 43.086 | 1.00 | 18.09 | B | N |
| ATOM | 2348 | C | ASN | B | 396 | 47.542 | 61.004 | 42.010 | 1.00 | 23.76 | B | C |
| ATOM | 2349 | O | ASN | B | 396 | 48.459 | 60.818 | 42.809 | 1.00 | 23.51 | B | O |
| ATOM | 2350 | N | TYR | B | 397 | 47.744 | 61.349 | 40.744 | 1.00 | 23.17 | B | N |
| ATOM | 2351 | CA | TYR | B | 397 | 49.085 | 61.486 | 40.209 | 1.00 | 23.84 | B | C |
| ATOM | 2352 | CB | TYR | B | 397 | 49.041 | 62.011 | 38.775 | 1.00 | 23.42 | B | C |
| ATOM | 2353 | CG | TYR | B | 397 | 50.370 | 61.862 | 38.077 | 1.00 | 26.38 | B | C |
| ATOM | 2354 | CD1 | TYR | B | 397 | 51.278 | 62.922 | 38.027 | 1.00 | 24.60 | B | C |
| ATOM | 2355 | CE1 | TYR | B | 397 | 52.523 | 62.776 | 37.427 | 1.00 | 24.72 | B | C |
| ATOM | 2356 | CD2 | TYR | B | 397 | 50.744 | 60.643 | 37.503 | 1.00 | 28.08 | B | C |
| ATOM | 2357 | CE2 | TYR | B | 397 | 51.992 | 60.486 | 36.898 | 1.00 | 28.37 | B | C |
| ATOM | 2358 | CZ | TYR | B | 397 | 52.873 | 61.556 | 36.865 | 1.00 | 28.68 | B | C |
| ATOM | 2359 | OH | TYR | B | 397 | 54.103 | 61.404 | 36.265 | 1.00 | 33.24 | B | O |
| ATOM | 2360 | C | TYR | B | 397 | 49.986 | 62.382 | 41.038 | 1.00 | 24.63 | B | C |
| ATOM | 2361 | O | TYR | B | 397 | 51.187 | 62.114 | 41.169 | 1.00 | 24.44 | B | O |
| ATOM | 2362 | N | ILE | B | 398 | 49.422 | 63.452 | 41.588 | 1.00 | 25.00 | B | N |
| ATOM | 2363 | CA | ILE | B | 398 | 50.215 | 64.369 | 42.401 | 1.00 | 24.34 | B | C |
| ATOM | 2364 | CB | ILE | B | 398 | 49.961 | 65.839 | 42.000 | 1.00 | 22.53 | B | C |
| ATOM | 2365 | CG2 | ILE | B | 398 | 50.516 | 66.089 | 40.620 | 1.00 | 23.96 | B | C |
| ATOM | 2366 | CG1 | ILE | B | 398 | 48.468 | 66.147 | 41.989 | 1.00 | 21.55 | B | C |
| ATOM | 2367 | CD1 | ILE | B | 398 | 48.183 | 67.633 | 41.961 | 1.00 | 18.71 | B | C |
| ATOM | 2368 | C | ILE | B | 398 | 49.970 | 64.198 | 43.896 | 1.00 | 24.11 | B | C |
| ATOM | 2369 | O | ILE | B | 398 | 50.219 | 65.109 | 44.683 | 1.00 | 23.12 | B | O |
| ATOM | 2370 | N | ASN | B | 399 | 49.483 | 63.021 | 44.281 | 1.00 | 24.85 | B | N |
| ATOM | 2371 | CA | ASN | B | 399 | 49.220 | 62.719 | 45.685 | 1.00 | 25.59 | B | C |
| ATOM | 2372 | CB | ASN | B | 399 | 50.544 | 62.678 | 46.454 | 1.00 | 25.97 | B | C |
| ATOM | 2373 | CG | ASN | B | 399 | 51.552 | 61.725 | 45.829 | 1.00 | 29.37 | B | C |
| ATOM | 2374 | OD1 | ASN | B | 399 | 51.242 | 60.562 | 45.566 | 1.00 | 32.56 | B | O |
| ATOM | 2375 | ND2 | ASN | B | 399 | 52.765 | 62.214 | 45.591 | 1.00 | 27.25 | B | N |
| ATOM | 2376 | C | ASN | B | 399 | 48.262 | 63.702 | 46.365 | 1.00 | 24.62 | B | C |
| ATOM | 2377 | O | ASN | B | 399 | 48.543 | 64.199 | 47.451 | 1.00 | 25.79 | B | O |
| ATOM | 2378 | N | GLY | B | 400 | 47.135 | 63.978 | 45.718 | 1.00 | 25.00 | B | N |
| ATOM | 2379 | CA | GLY | B | 400 | 46.148 | 64.883 | 46.280 | 1.00 | 24.48 | B | C |
| ATOM | 2380 | C | GLY | B | 400 | 46.689 | 66.188 | 46.833 | 1.00 | 22.32 | B | C |
| ATOM | 2381 | O | GLY | B | 400 | 46.128 | 66.755 | 47.772 | 1.00 | 23.92 | B | O |
| ATOM | 2382 | N | GLU | B | 401 | 47.768 | 66.684 | 46.249 | 1.00 | 21.17 | B | N |
| ATOM | 2383 | CA | GLU | B | 401 | 48.362 | 67.932 | 46.718 | 1.00 | 21.89 | B | C |
| ATOM | 2384 | CB | GLU | B | 401 | 49.672 | 68.187 | 45.979 | 1.00 | 21.16 | B | C |
| ATOM | 2385 | CG | GLU | B | 401 | 50.190 | 69.587 | 46.156 | 1.00 | 21.72 | B | C |
| ATOM | 2386 | CD | GLU | B | 401 | 51.503 | 69.799 | 45.464 | 1.00 | 22.53 | B | C |
| ATOM | 2387 | OE1 | GLU | B | 401 | 52.364 | 68.899 | 45.556 | 1.00 | 25.15 | B | O |
| ATOM | 2388 | OE2 | GLU | B | 401 | 51.669 | 70.864 | 44.832 | 1.00 | 23.90 | B | O |
| ATOM | 2389 | C | GLU | B | 401 | 47.449 | 69.150 | 46.560 | 1.00 | 21.85 | B | C |
| ATOM | 2390 | O | GLU | B | 401 | 47.449 | 70.046 | 47.403 | 1.00 | 22.89 | B | O |
| ATOM | 2391 | N | TYR | B | 402 | 46.685 | 69.186 | 45.473 | 1.00 | 22.18 | B | N |
| ATOM | 2392 | CA | TYR | B | 402 | 45.775 | 70.300 | 45.201 | 1.00 | 21.46 | B | C |
| ATOM | 2393 | CB | TYR | B | 402 | 45.199 | 70.169 | 43.788 | 1.00 | 23.38 | B | C |
| ATOM | 2394 | CG | TYR | B | 402 | 46.121 | 70.648 | 42.676 | 1.00 | 22.56 | B | C |
| ATOM | 2395 | CD1 | TYR | B | 402 | 47.386 | 71.167 | 42.957 | 1.00 | 21.63 | B | C |
| ATOM | 2396 | CE1 | TYR | B | 402 | 48.213 | 71.641 | 41.939 | 1.00 | 21.23 | B | C |
| ATOM | 2397 | CD2 | TYR | B | 402 | 45.708 | 70.609 | 41.344 | 1.00 | 19.54 | B | C |
| ATOM | 2398 | CE2 | TYR | B | 402 | 46.526 | 71.079 | 40.320 | 1.00 | 21.13 | B | C |
| ATOM | 2399 | CZ | TYR | B | 402 | 47.774 | 71.596 | 40.621 | 1.00 | 21.44 | B | C |
| ATOM | 2400 | OH | TYR | B | 402 | 48.572 | 72.084 | 39.609 | 1.00 | 17.00 | B | O |
| ATOM | 2401 | C | TYR | B | 402 | 44.630 | 70.369 | 46.213 | 1.00 | 20.80 | B | C |
| ATOM | 2402 | O | TYR | B | 402 | 44.247 | 71.451 | 46.655 | 1.00 | 20.17 | B | O |
| ATOM | 2403 | N | PHE | B | 403 | 44.088 | 69.209 | 46.568 | 1.00 | 18.76 | B | N |
| ATOM | 2404 | CA | PHE | B | 403 | 42.995 | 69.114 | 47.533 | 1.00 | 16.55 | B | C |
| ATOM | 2405 | CB | PHE | B | 403 | 42.547 | 67.658 | 47.661 | 1.00 | 16.66 | B | C |
| ATOM | 2406 | CG | PHE | B | 403 | 41.274 | 67.474 | 48.428 | 1.00 | 15.19 | B | C |
| ATOM | 2407 | CD1 | PHE | B | 403 | 40.306 | 68.465 | 48.448 | 1.00 | 15.07 | B | C |
| ATOM | 2408 | CD2 | PHE | B | 403 | 41.037 | 66.292 | 49.120 | 1.00 | 15.75 | B | C |
| ATOM | 2409 | CE1 | PHE | B | 403 | 39.120 | 68.286 | 49.141 | 1.00 | 14.24 | B | C |
| ATOM | 2410 | CE2 | PHE | B | 403 | 39.855 | 66.102 | 49.816 | 1.00 | 15.36 | B | C |
| ATOM | 2411 | CZ | PHE | B | 403 | 38.893 | 67.103 | 49.825 | 1.00 | 15.82 | B | C |
| ATOM | 2412 | C | PHE | B | 403 | 43.489 | 69.621 | 48.883 | 1.00 | 17.01 | B | C |
| ATOM | 2413 | O | PHE | B | 403 | 42.793 | 70.351 | 49.584 | 1.00 | 16.77 | B | O |
| ATOM | 2414 | N | ALA | B | 404 | 44.705 | 69.232 | 49.238 | 1.00 | 17.03 | B | N |
| ATOM | 2415 | CA | ALA | B | 404 | 45.303 | 69.659 | 50.495 | 1.00 | 17.81 | B | C |
| ATOM | 2416 | CB | ALA | B | 404 | 46.670 | 69.013 | 50.672 | 1.00 | 14.63 | B | C |
| ATOM | 2417 | C | ALA | B | 404 | 45.439 | 71.174 | 50.518 | 1.00 | 19.10 | B | C |
| ATOM | 2418 | O | ALA | B | 404 | 45.094 | 71.817 | 51.503 | 1.00 | 21.59 | B | O |
| ATOM | 2419 | N | THR | B | 405 | 45.935 | 71.746 | 49.426 | 1.00 | 19.77 | B | N |
| ATOM | 2420 | CA | THR | B | 405 | 46.114 | 73.187 | 49.358 | 1.00 | 17.32 | B | C |
| ATOM | 2421 | CB | THR | B | 405 | 46.797 | 73.596 | 48.051 | 1.00 | 17.59 | B | C |
| ATOM | 2422 | OG1 | THR | B | 405 | 47.992 | 72.824 | 47.888 | 1.00 | 17.02 | B | O |
| ATOM | 2423 | CG2 | THR | B | 405 | 47.158 | 75.071 | 48.074 | 1.00 | 7.34 | B | C |
| ATOM | 2424 | C | THR | B | 405 | 44.809 | 73.952 | 49.503 | 1.00 | 18.95 | B | C |
| ATOM | 2425 | O | THR | B | 405 | 44.767 | 74.984 | 50.184 | 1.00 | 20.34 | B | O |
| ATOM | 2426 | N | ILE | B | 406 | 43.746 | 73.459 | 48.870 | 1.00 | 19.59 | B | N |
| ATOM | 2427 | CA | ILE | B | 406 | 42.439 | 74.119 | 48.960 | 1.00 | 19.80 | B | C |
| ATOM | 2428 | CB | ILE | B | 406 | 41.371 | 73.420 | 48.089 | 1.00 | 20.27 | B | C |
| ATOM | 2429 | CG2 | ILE | B | 406 | 40.022 | 74.090 | 48.286 | 1.00 | 17.42 | B | C |
| ATOM | 2430 | CG1 | ILE | B | 406 | 41.775 | 73.480 | 46.615 | 1.00 | 22.19 | B | C |
| ATOM | 2431 | CD1 | ILE | B | 406 | 40.915 | 72.632 | 45.698 | 1.00 | 22.25 | B | C |
| ATOM | 2432 | C | ILE | B | 406 | 41.966 | 74.060 | 50.405 | 1.00 | 20.85 | B | C |
| ATOM | 2433 | O | ILE | B | 406 | 41.590 | 75.076 | 50.993 | 1.00 | 22.19 | B | O |
| ATOM | 2434 | N | ILE | B | 407 | 42.003 | 72.856 | 50.969 | 1.00 | 20.14 | B | N |
| ATOM | 2435 | CA | ILE | B | 407 | 41.581 | 72.618 | 52.343 | 1.00 | 20.89 | B | C |
| ATOM | 2436 | CB | ILE | B | 407 | 41.766 | 71.137 | 52.729 | 1.00 | 19.37 | B | C |
| ATOM | 2437 | CG2 | ILE | B | 407 | 42.003 | 71.009 | 54.220 | 1.00 | 17.85 | B | C |
| ATOM | 2438 | CG1 | ILE | B | 407 | 40.522 | 70.345 | 52.323 | 1.00 | 17.02 | B | C |
| ATOM | 2439 | CD1 | ILE | B | 407 | 40.733 | 68.860 | 52.301 | 1.00 | 16.54 | B | C |
| ATOM | 2440 | C | ILE | B | 407 | 42.327 | 73.488 | 53.344 | 1.00 | 20.84 | B | C |
| ATOM | 2441 | O | ILE | B | 407 | 41.737 | 73.962 | 54.314 | 1.00 | 21.84 | B | O |
| ATOM | 2442 | N | LYS | B | 408 | 43.619 | 73.697 | 53.121 | 1.00 | 20.51 | B | N |
| ATOM | 2443 | CA | LYS | B | 408 | 44.391 | 74.537 | 54.030 | 1.00 | 20.08 | B | C |
| ATOM | 2444 | CB | LYS | B | 408 | 45.886 | 74.368 | 53.782 | 1.00 | 19.46 | B | C |
| ATOM | 2445 | CG | LYS | B | 408 | 46.464 | 73.102 | 54.395 | 1.00 | 21.27 | B | C |
| ATOM | 2446 | CD | LYS | B | 408 | 47.511 | 72.484 | 53.486 | 1.00 | 25.77 | B | C |
| ATOM | 2447 | CE | LYS | B | 408 | 48.907 | 72.971 | 53.835 | 1.00 | 25.44 | B | C |
| ATOM | 2448 | NZ | LYS | B | 408 | 49.048 | 73.286 | 55.288 | 1.00 | 29.30 | B | N |
| ATOM | 2449 | C | LYS | B | 408 | 43.998 | 75.997 | 53.860 | 1.00 | 20.40 | B | C |
| ATOM | 2450 | O | LYS | B | 408 | 44.136 | 76.797 | 54.782 | 1.00 | 22.04 | B | O |
| ATOM | 2451 | N | GLU | B | 409 | 43.494 | 76.343 | 52.681 | 1.00 | 21.16 | B | N |
| ATOM | 2452 | CA | GLU | B | 409 | 43.078 | 77.714 | 52.421 | 1.00 | 20.74 | B | C |
| ATOM | 2453 | CB | GLU | B | 409 | 42.943 | 77.955 | 50.911 | 1.00 | 19.83 | B | C |
| ATOM | 2454 | CG | GLU | B | 409 | 44.240 | 78.393 | 50.257 | 1.00 | 19.71 | B | C |
| ATOM | 2455 | CD | GLU | B | 409 | 44.145 | 78.520 | 48.744 | 1.00 | 22.41 | B | C |
| ATOM | 2456 | OE1 | GLU | B | 409 | 43.058 | 78.289 | 48.177 | 1.00 | 21.65 | B | O |
| ATOM | 2457 | OE2 | GLU | B | 409 | 45.174 | 78.855 | 48.115 | 1.00 | 24.96 | B | O |
| ATOM | 2458 | C | GLU | B | 409 | 41.750 | 77.976 | 53.127 | 1.00 | 19.02 | B | C |
| ATOM | 2459 | O | GLU | B | 409 | 41.473 | 79.095 | 53.563 | 1.00 | 19.07 | B | O |
| ATOM | 2460 | N | VAL | B | 410 | 40.936 | 76.933 | 53.239 | 1.00 | 15.57 | B | N |
| ATOM | 2461 | CA | VAL | B | 410 | 39.641 | 77.032 | 53.906 | 1.00 | 17.26 | B | C |
| ATOM | 2462 | CB | VAL | B | 410 | 38.777 | 75.779 | 53.637 | 1.00 | 15.97 | B | C |
| ATOM | 2463 | CG1 | VAL | B | 410 | 37.528 | 75.813 | 54.510 | 1.00 | 12.74 | B | C |
| ATOM | 2464 | CG2 | VAL | B | 410 | 38.412 | 75.704 | 52.156 | 1.00 | 8.70 | B | C |
| ATOM | 2465 | C | VAL | B | 410 | 39.859 | 77.158 | 55.414 | 1.00 | 18.50 | B | C |
| ATOM | 2466 | O | VAL | B | 410 | 39.261 | 78.005 | 56.072 | 1.00 | 18.15 | B | O |
| ATOM | 2467 | N | GLY | B | 411 | 40.724 | 76.302 | 55.947 | 1.00 | 19.29 | B | N |
| ATOM | 2468 | CA | GLY | B | 411 | 41.019 | 76.333 | 57.364 | 1.00 | 20.68 | B | C |
| ATOM | 2469 | C | GLY | B | 411 | 41.554 | 77.686 | 57.783 | 1.00 | 23.03 | B | C |
| ATOM | 2470 | O | GLY | B | 411 | 41.234 | 78.182 | 58.862 | 1.00 | 27.14 | B | O |
| ATOM | 2471 | N | ALA | B | 412 | 42.372 | 78.293 | 56.935 | 1.00 | 23.27 | B | N |
| ATOM | 2472 | CA | ALA | B | 412 | 42.932 | 79.600 | 57.246 | 1.00 | 21.90 | B | C |
| ATOM | 2473 | CB | ALA | B | 412 | 43.987 | 79.975 | 56.217 | 1.00 | 22.05 | B | C |
| ATOM | 2474 | C | ALA | B | 412 | 41.838 | 80.660 | 57.279 | 1.00 | 22.58 | B | C |
| ATOM | 2475 | O | ALA | B | 412 | 41.923 | 81.618 | 58.039 | 1.00 | 22.32 | B | O |
| ATOM | 2476 | N | ASP | B | 413 | 40.815 | 80.496 | 56.450 | 1.00 | 22.26 | B | N |
| ATOM | 2477 | CA | ASP | B | 413 | 39.720 | 81.460 | 56.421 | 1.00 | 24.59 | B | C |
| ATOM | 2478 | CB | ASP | B | 413 | 38.773 | 81.166 | 55.253 | 1.00 | 26.88 | B | C |
| ATOM | 2479 | CG | ASP | B | 413 | 39.210 | 81.832 | 53.954 | 1.00 | 27.63 | B | C |
| ATOM | 2480 | OD1 | ASP | B | 413 | 38.820 | 81.333 | 52.878 | 1.00 | 31.78 | B | O |
| ATOM | 2481 | OD2 | ASP | B | 413 | 39.939 | 82.845 | 54.001 | 1.00 | 25.09 | B | O |
| ATOM | 2482 | C | ASP | B | 413 | 38.947 | 81.378 | 57.736 | 1.00 | 25.66 | B | C |
| ATOM | 2483 | O | ASP | B | 413 | 38.472 | 82.387 | 58.260 | 1.00 | 26.13 | B | O |
| ATOM | 2484 | N | LEU | B | 414 | 38.825 | 80.159 | 58.254 | 1.00 | 24.99 | B | N |
| ATOM | 2485 | CA | LEU | B | 414 | 38.123 | 79.896 | 59.501 | 1.00 | 24.25 | B | C |
| ATOM | 2486 | CB | LEU | B | 414 | 38.080 | 78.386 | 59.761 | 1.00 | 22.31 | B | C |
| ATOM | 2487 | CG | LEU | B | 414 | 36.825 | 77.586 | 59.391 | 1.00 | 21.78 | B | C |
| ATOM | 2488 | CD1 | LEU | B | 414 | 35.954 | 78.365 | 58.438 | 1.00 | 17.71 | B | C |
| ATOM | 2489 | CD2 | LEU | B | 414 | 37.239 | 76.267 | 58.775 | 1.00 | 19.71 | B | C |
| ATOM | 2490 | C | LEU | B | 414 | 38.834 | 80.596 | 60.655 | 1.00 | 24.00 | B | C |
| ATOM | 2491 | O | LEU | B | 414 | 38.204 | 81.309 | 61.441 | 1.00 | 24.64 | B | O |
| ATOM | 2492 | N | VAL | B | 415 | 40.147 | 80.390 | 60.744 | 1.00 | 23.79 | B | N |
| ATOM | 2493 | CA | VAL | B | 415 | 40.965 | 80.986 | 61.795 | 1.00 | 23.58 | B | C |
| ATOM | 2494 | CB | VAL | B | 415 | 42.450 | 80.624 | 61.617 | 1.00 | 20.85 | B | C |
| ATOM | 2495 | CG1 | VAL | B | 415 | 43.306 | 81.472 | 62.540 | 1.00 | 20.03 | B | C |
| ATOM | 2496 | CG2 | VAL | B | 415 | 42.666 | 79.155 | 61.910 | 1.00 | 16.09 | B | C |
| ATOM | 2497 | C | VAL | B | 415 | 40.839 | 82.504 | 61.800 | 1.00 | 25.73 | B | C |
| ATOM | 2498 | O | VAL | B | 415 | 40.990 | 83.147 | 62.840 | 1.00 | 27.46 | B | O |
| ATOM | 2499 | N | ASP | B | 416 | 40.563 | 83.073 | 60.633 | 1.00 | 28.17 | B | N |
| ATOM | 2500 | CA | ASP | B | 416 | 40.416 | 84.517 | 60.498 | 1.00 | 28.70 | B | C |
| ATOM | 2501 | CB | ASP | B | 416 | 40.451 | 84.922 | 59.028 | 1.00 | 33.31 | B | C |
| ATOM | 2502 | CG | ASP | B | 416 | 41.843 | 85.250 | 58.550 | 1.00 | 39.34 | B | C |
| ATOM | 2503 | OD1 | ASP | B | 416 | 41.979 | 85.647 | 57.371 | 1.00 | 46.83 | B | O |
| ATOM | 2504 | OD2 | ASP | B | 416 | 42.799 | 85.109 | 59.347 | 1.00 | 41.91 | B | O |
| ATOM | 2505 | C | ASP | B | 416 | 39.104 | 84.973 | 61.093 | 1.00 | 27.01 | B | C |
| ATOM | 2506 | O | ASP | B | 416 | 39.053 | 85.977 | 61.796 | 1.00 | 27.76 | B | O |
| ATOM | 2507 | N | ALA | B | 417 | 38.043 | 84.233 | 60.791 | 1.00 | 23.54 | B | N |
| ATOM | 2508 | CA | ALA | B | 417 | 36.710 | 84.548 | 61.290 | 1.00 | 23.93 | B | C |
| ATOM | 2509 | CB | ALA | B | 417 | 35.665 | 83.782 | 60.497 | 1.00 | 25.51 | B | C |
| ATOM | 2510 | C | ALA | B | 417 | 36.615 | 84.191 | 62.765 | 1.00 | 21.32 | B | C |
| ATOM | 2511 | O | ALA | B | 417 | 35.682 | 84.586 | 63.451 | 1.00 | 21.47 | B | O |
| ATOM | 2512 | N | LYS | B | 418 | 37.579 | 83.405 | 63.225 | 1.00 | 21.67 | B | N |
| ATOM | 2513 | CA | LYS | B | 418 | 37.684 | 82.998 | 64.620 | 1.00 | 21.49 | B | C |
| ATOM | 2514 | CB | LYS | B | 418 | 37.899 | 84.240 | 65.491 | 1.00 | 21.89 | B | C |
| ATOM | 2515 | CG | LYS | B | 418 | 38.015 | 83.944 | 66.984 | 1.00 | 21.23 | B | C |
| ATOM | 2516 | CD | LYS | B | 418 | 38.506 | 85.172 | 67.749 | 1.00 | 25.79 | B | C |
| ATOM | 2517 | CE | LYS | B | 418 | 38.834 | 84.851 | 69.207 | 1.00 | 27.10 | B | C |
| ATOM | 2518 | NZ | LYS | B | 418 | 38.584 | 86.013 | 70.111 | 1.00 | 27.58 | B | N |
| ATOM | 2519 | C | LYS | B | 418 | 36.607 | 82.142 | 65.284 | 1.00 | 20.18 | B | C |
| ATOM | 2520 | O | LYS | B | 418 | 36.938 | 81.158 | 65.946 | 1.00 | 22.48 | B | O |
| ATOM | 2521 | N | TYR | B | 419 | 35.334 | 82.495 | 65.117 | 1.00 | 16.66 | B | N |
| ATOM | 2522 | CA | TYR | B | 419 | 34.266 | 81.778 | 65.812 | 1.00 | 15.55 | B | C |
| ATOM | 2523 | CB | TYR | B | 419 | 33.189 | 82.789 | 66.234 | 1.00 | 14.80 | B | C |
| ATOM | 2524 | CG | TYR | B | 419 | 33.765 | 83.926 | 67.048 | 1.00 | 15.58 | B | C |
| ATOM | 2525 | CD1 | TYR | B | 419 | 34.149 | 83.728 | 68.366 | 1.00 | 18.67 | B | C |
| ATOM | 2526 | CE1 | TYR | B | 419 | 34.759 | 84.740 | 69.107 | 1.00 | 20.53 | B | C |
| ATOM | 2527 | CD2 | TYR | B | 419 | 33.998 | 85.180 | 66.481 | 1.00 | 17.50 | B | C |
| ATOM | 2528 | CE2 | TYR | B | 419 | 34.611 | 86.206 | 67.213 | 1.00 | 18.73 | B | C |
| ATOM | 2529 | CZ | TYR | B | 419 | 34.992 | 85.972 | 68.527 | 1.00 | 22.08 | B | C |
| ATOM | 2530 | OH | TYR | B | 419 | 35.634 | 86.943 | 69.263 | 1.00 | 23.18 | B | O |
| ATOM | 2531 | C | TYR | B | 419 | 33.608 | 80.539 | 65.212 | 1.00 | 16.00 | B | C |
| ATOM | 2532 | O | TYR | B | 419 | 32.927 | 79.797 | 65.929 | 1.00 | 16.46 | B | O |
| ATOM | 2533 | N | GLN | B | 420 | 33.790 | 80.294 | 63.920 | 1.00 | 16.41 | B | N |
| ATOM | 2534 | CA | GLN | B | 420 | 33.191 | 79.106 | 63.316 | 1.00 | 14.18 | B | C |
| ATOM | 2535 | CB | GLN | B | 420 | 32.564 | 79.447 | 61.970 | 1.00 | 15.20 | B | C |
| ATOM | 2536 | CG | GLN | B | 420 | 31.229 | 80.158 | 62.085 | 1.00 | 21.65 | B | C |
| ATOM | 2537 | CD | GLN | B | 420 | 31.380 | 81.578 | 62.591 | 1.00 | 24.54 | B | C |
| ATOM | 2538 | OE1 | GLN | B | 420 | 30.860 | 81.933 | 63.649 | 1.00 | 28.23 | B | O |
| ATOM | 2539 | NE2 | GLN | B | 420 | 32.100 | 82.398 | 61.837 | 1.00 | 25.10 | B | N |
| ATOM | 2540 | C | GLN | B | 420 | 34.221 | 77.994 | 63.143 | 1.00 | 13.10 | B | C |
| ATOM | 2541 | O | GLN | B | 420 | 35.364 | 78.243 | 62.764 | 1.00 | 10.95 | B | O |
| ATOM | 2542 | N | HIS | B | 421 | 33.803 | 76.770 | 63.443 | 1.00 | 10.38 | B | N |
| ATOM | 2543 | CA | HIS | B | 421 | 34.656 | 75.597 | 63.334 | 1.00 | 10.35 | B | C |
| ATOM | 2544 | CB | HIS | B | 421 | 34.865 | 74.962 | 64.720 | 1.00 | 8.46 | B | C |
| ATOM | 2545 | CG | HIS | B | 421 | 35.595 | 75.839 | 65.687 | 1.00 | 7.79 | B | C |
| ATOM | 2546 | CD2 | HIS | B | 421 | 35.215 | 76.972 | 66.326 | 1.00 | 8.07 | B | C |
| ATOM | 2547 | ND1 | HIS | B | 421 | 36.890 | 75.592 | 66.090 | 1.00 | 9.97 | B | N |
| ATOM | 2548 | CE1 | HIS | B | 421 | 37.276 | 76.531 | 66.933 | 1.00 | 5.63 | B | C |
| ATOM | 2549 | NE2 | HIS | B | 421 | 36.279 | 77.379 | 67.094 | 1.00 | 8.76 | B | N |
| ATOM | 2550 | C | HIS | B | 421 | 33.954 | 74.603 | 62.412 | 1.00 | 11.99 | B | C |
| ATOM | 2551 | O | HIS | B | 421 | 32.779 | 74.790 | 62.083 | 1.00 | 8.19 | B | O |
| ATOM | 2552 | N | ALA | B | 422 | 34.657 | 73.539 | 62.015 | 1.00 | 12.17 | B | N |
| ATOM | 2553 | CA | ALA | B | 422 | 34.075 | 72.537 | 61.127 | 1.00 | 10.35 | B | C |
| ATOM | 2554 | CB | ALA | B | 422 | 34.311 | 72.936 | 59.685 | 1.00 | 9.74 | B | C |
| ATOM | 2555 | C | ALA | B | 422 | 34.642 | 71.148 | 61.379 | 1.00 | 10.86 | B | C |
| ATOM | 2556 | O | ALA | B | 422 | 35.785 | 71.008 | 61.800 | 1.00 | 15.70 | B | O |
| ATOM | 2557 | N | GLU | B | 423 | 33.838 | 70.122 | 61.116 | 1.00 | 11.49 | B | N |
| ATOM | 2558 | CA | GLU | B | 423 | 34.251 | 68.729 | 61.303 | 1.00 | 14.32 | B | C |
| ATOM | 2559 | CB | GLU | B | 423 | 33.303 | 68.024 | 62.280 | 1.00 | 12.55 | B | C |
| ATOM | 2560 | CG | GLU | B | 423 | 33.196 | 68.651 | 63.653 | 1.00 | 12.66 | B | C |
| ATOM | 2561 | CD | GLU | B | 423 | 32.418 | 67.769 | 64.609 | 1.00 | 16.31 | B | C |
| ATOM | 2562 | OE1 | GLU | B | 423 | 33.034 | 66.911 | 65.272 | 1.00 | 19.02 | B | O |
| ATOM | 2563 | OE2 | GLU | B | 423 | 31.184 | 67.923 | 64.694 | 1.00 | 18.10 | B | O |
| ATOM | 2564 | C | GLU | B | 423 | 34.237 | 67.970 | 59.963 | 1.00 | 13.62 | B | C |
| ATOM | 2565 | O | GLU | B | 423 | 33.456 | 67.030 | 59.772 | 1.00 | 11.35 | B | O |
| ATOM | 2566 | N | PRO | B | 424 | 35.115 | 68.362 | 59.026 | 1.00 | 13.75 | B | N |
| ATOM | 2567 | CD | PRO | B | 424 | 36.107 | 69.436 | 59.177 | 1.00 | 13.57 | B | C |
| ATOM | 2568 | CA | PRO | B | 424 | 35.204 | 67.732 | 57.705 | 1.00 | 13.83 | B | C |
| ATOM | 2569 | CB | PRO | B | 424 | 36.300 | 68.532 | 57.007 | 1.00 | 11.58 | B | C |
| ATOM | 2570 | CG | PRO | B | 424 | 37.093 | 69.126 | 58.106 | 1.00 | 12.45 | B | C |
| ATOM | 2571 | C | PRO | B | 424 | 35.502 | 66.233 | 57.717 | 1.00 | 13.70 | B | C |
| ATOM | 2572 | O | PRO | B | 424 | 36.388 | 65.764 | 58.421 | 1.00 | 13.73 | B | O |
| ATOM | 2573 | N | ARG | B | 425 | 34.750 | 65.499 | 56.905 | 1.00 | 15.58 | B | N |
| ATOM | 2574 | CA | ARG | B | 425 | 34.867 | 64.051 | 56.775 | 1.00 | 14.01 | B | C |
| ATOM | 2575 | CB | ARG | B | 425 | 33.465 | 63.453 | 56.584 | 1.00 | 12.03 | B | C |
| ATOM | 2576 | CG | ARG | B | 425 | 32.941 | 62.670 | 57.775 | 1.00 | 15.19 | B | C |
| ATOM | 2577 | CD | ARG | B | 425 | 31.586 | 63.163 | 58.261 | 1.00 | 14.34 | B | C |
| ATOM | 2578 | NE | ARG | B | 425 | 31.687 | 64.432 | 58.973 | 1.00 | 13.76 | B | N |
| ATOM | 2579 | CZ | ARG | B | 425 | 30.878 | 64.812 | 59.961 | 1.00 | 15.04 | B | C |
| ATOM | 2580 | NH1 | ARG | B | 425 | 29.889 | 64.025 | 60.382 | 1.00 | 6.56 | B | N |
| ATOM | 2581 | NH2 | ARG | B | 425 | 31.049 | 66.006 | 60.517 | 1.00 | 14.39 | B | N |
| ATOM | 2582 | C | ARG | B | 425 | 35.758 | 63.669 | 55.585 | 1.00 | 15.13 | B | C |
| ATOM | 2583 | O | ARG | B | 425 | 35.568 | 64.176 | 54.481 | 1.00 | 14.42 | B | O |
| ATOM | 2584 | N | LEU | B | 426 | 36.732 | 62.788 | 55.821 | 1.00 | 15.65 | B | N |
| ATOM | 2585 | CA | LEU | B | 426 | 37.646 | 62.310 | 54.777 | 1.00 | 14.93 | B | C |
| ATOM | 2586 | CB | LEU | B | 426 | 39.095 | 62.311 | 55.276 | 1.00 | 15.19 | B | C |
| ATOM | 2587 | CG | LEU | B | 426 | 39.781 | 63.668 | 55.470 | 1.00 | 17.79 | B | C |
| ATOM | 2588 | CD1 | LEU | B | 426 | 40.982 | 63.514 | 56.403 | 1.00 | 12.63 | B | C |
| ATOM | 2589 | CD2 | LEU | B | 426 | 40.217 | 64.225 | 54.121 | 1.00 | 13.52 | B | C |
| ATOM | 2590 | C | LEU | B | 426 | 37.232 | 60.882 | 54.434 | 1.00 | 15.18 | B | C |
| ATOM | 2591 | O | LEU | B | 426 | 36.777 | 60.144 | 55.308 | 1.00 | 17.86 | B | O |
| ATOM | 2592 | N | SER | B | 427 | 37.406 | 60.481 | 53.177 | 1.00 | 15.64 | B | N |
| ATOM | 2593 | CA | SER | B | 427 | 36.997 | 59.142 | 52.747 | 1.00 | 18.08 | B | C |
| ATOM | 2594 | CB | SER | B | 427 | 36.482 | 59.171 | 51.303 | 1.00 | 15.33 | B | C |
| ATOM | 2595 | OG | SER | B | 427 | 35.470 | 60.137 | 51.130 | 1.00 | 18.75 | B | O |
| ATOM | 2596 | C | SER | B | 427 | 38.036 | 58.034 | 52.831 | 1.00 | 16.87 | B | C |
| ATOM | 2597 | O | SER | B | 427 | 39.208 | 58.236 | 52.528 | 1.00 | 19.07 | B | O |
| ATOM | 2598 | N | ILE | B | 428 | 37.568 | 56.861 | 53.239 | 1.00 | 14.77 | B | N |
| ATOM | 2599 | CA | ILE | B | 428 | 38.362 | 55.642 | 53.325 | 1.00 | 15.70 | B | C |
| ATOM | 2600 | CB | ILE | B | 428 | 38.756 | 55.301 | 54.779 | 1.00 | 15.81 | B | C |
| ATOM | 2601 | CG2 | ILE | B | 428 | 39.031 | 53.806 | 54.918 | 1.00 | 11.18 | B | C |
| ATOM | 2602 | CG1 | ILE | B | 428 | 39.992 | 56.117 | 55.183 | 1.00 | 12.64 | B | C |
| ATOM | 2603 | CD1 | ILE | B | 428 | 41.306 | 55.616 | 54.612 | 1.00 | 9.68 | B | C |
| ATOM | 2604 | C | ILE | B | 428 | 37.313 | 54.669 | 52.806 | 1.00 | 17.44 | B | C |
| ATOM | 2605 | O | ILE | B | 428 | 36.326 | 54.395 | 53.483 | 1.00 | 15.69 | B | O |
| ATOM | 2606 | N | TYR | B | 429 | 37.515 | 54.177 | 51.587 | 1.00 | 20.08 | B | N |
| ATOM | 2607 | CA | TYR | B | 429 | 36.540 | 53.302 | 50.936 | 1.00 | 20.97 | B | C |
| ATOM | 2608 | CB | TYR | B | 429 | 36.686 | 53.423 | 49.413 | 1.00 | 17.90 | B | C |
| ATOM | 2609 | CG | TYR | B | 429 | 36.631 | 54.848 | 48.886 | 1.00 | 16.16 | B | C |
| ATOM | 2610 | CD1 | TYR | B | 429 | 37.790 | 55.618 | 48.763 | 1.00 | 16.37 | B | C |
| ATOM | 2611 | CE1 | TYR | B | 429 | 37.742 | 56.923 | 48.262 | 1.00 | 12.41 | B | C |
| ATOM | 2612 | CD2 | TYR | B | 429 | 35.420 | 55.421 | 48.495 | 1.00 | 13.24 | B | C |
| ATOM | 2613 | CE2 | TYR | B | 429 | 35.361 | 56.711 | 47.998 | 1.00 | 8.44 | B | C |
| ATOM | 2614 | CZ | TYR | B | 429 | 36.519 | 57.459 | 47.883 | 1.00 | 16.40 | B | C |
| ATOM | 2615 | OH | TYR | B | 429 | 36.445 | 58.750 | 47.396 | 1.00 | 22.91 | B | O |
| ATOM | 2616 | C | TYR | B | 429 | 36.529 | 51.831 | 51.318 | 1.00 | 21.44 | B | C |
| ATOM | 2617 | O | TYR | B | 429 | 35.475 | 51.198 | 51.304 | 1.00 | 21.98 | B | O |
| ATOM | 2618 | N | GLY | B | 430 | 37.685 | 51.283 | 51.666 | 1.00 | 21.24 | B | N |
| ATOM | 2619 | CA | GLY | B | 430 | 37.725 | 49.872 | 52.000 | 1.00 | 21.28 | B | C |
| ATOM | 2620 | C | GLY | B | 430 | 37.941 | 49.089 | 50.715 | 1.00 | 22.64 | B | C |
| ATOM | 2621 | O | GLY | B | 430 | 37.699 | 47.887 | 50.649 | 1.00 | 20.88 | B | O |
| ATOM | 2622 | N | ARG | B | 431 | 38.404 | 49.795 | 49.686 | 1.00 | 23.65 | B | N |
| ATOM | 2623 | CA | ARG | B | 431 | 38.676 | 49.204 | 48.382 | 1.00 | 23.84 | B | C |
| ATOM | 2624 | CB | ARG | B | 431 | 38.613 | 50.292 | 47.305 | 1.00 | 24.83 | B | C |
| ATOM | 2625 | CG | ARG | B | 431 | 39.035 | 49.844 | 45.919 | 1.00 | 28.60 | B | C |
| ATOM | 2626 | CD | ARG | B | 431 | 39.480 | 51.026 | 45.072 | 1.00 | 28.80 | B | C |
| ATOM | 2627 | NE | ARG | B | 431 | 40.643 | 51.714 | 45.636 | 1.00 | 31.07 | B | N |
| ATOM | 2628 | CZ | ARG | B | 431 | 40.643 | 52.990 | 46.017 | 1.00 | 30.76 | B | C |
| ATOM | 2629 | NH1 | ARG | B | 431 | 39.540 | 53.717 | 45.897 | 1.00 | 34.22 | B | N |
| ATOM | 2630 | NH2 | ARG | B | 431 | 41.745 | 53.548 | 46.501 | 1.00 | 28.15 | B | N |
| ATOM | 2631 | C | ARG | B | 431 | 40.052 | 48.555 | 48.390 | 1.00 | 22.44 | B | C |
| ATOM | 2632 | O | ARG | B | 431 | 40.262 | 47.518 | 47.771 | 1.00 | 19.86 | B | O |
| ATOM | 2633 | N | SER | B | 432 | 40.984 | 49.173 | 49.110 | 1.00 | 26.45 | B | N |
| ATOM | 2634 | CA | SER | B | 432 | 42.357 | 48.677 | 49.209 | 1.00 | 29.49 | B | C |
| ATOM | 2635 | CB | SER | B | 432 | 43.261 | 49.433 | 48.228 | 1.00 | 28.93 | B | C |
| ATOM | 2636 | OG | SER | B | 432 | 44.626 | 49.217 | 48.528 | 1.00 | 28.56 | B | O |
| ATOM | 2637 | C | SER | B | 432 | 42.889 | 48.842 | 50.635 | 1.00 | 31.19 | B | C |
| ATOM | 2638 | O | SER | B | 432 | 42.496 | 49.764 | 51.352 | 1.00 | 32.08 | B | O |
| ATOM | 2639 | N | PRO | B | 433 | 43.809 | 47.959 | 51.059 | 1.00 | 32.97 | B | N |
| ATOM | 2640 | CD | PRO | B | 433 | 44.376 | 46.841 | 50.280 | 1.00 | 32.45 | B | C |
| ATOM | 2641 | CA | PRO | B | 433 | 44.372 | 48.032 | 52.415 | 1.00 | 31.04 | B | C |
| ATOM | 2642 | CB | PRO | B | 433 | 44.922 | 46.628 | 52.653 | 1.00 | 28.56 | B | C |
| ATOM | 2643 | CG | PRO | B | 433 | 45.248 | 46.113 | 51.284 | 1.00 | 30.49 | B | C |
| ATOM | 2644 | C | PRO | B | 433 | 45.432 | 49.113 | 52.629 | 1.00 | 30.49 | B | C |
| ATOM | 2645 | O | PRO | B | 433 | 45.792 | 49.417 | 53.765 | 1.00 | 31.65 | B | O |
| ATOM | 2646 | N | ASP | B | 434 | 45.929 | 49.701 | 51.549 | 1.00 | 29.58 | B | N |
| ATOM | 2647 | CA | ASP | B | 434 | 46.944 | 50.740 | 51.683 | 1.00 | 29.41 | B | C |
| ATOM | 2648 | CB | ASP | B | 434 | 47.970 | 50.631 | 50.542 | 1.00 | 34.93 | B | C |
| ATOM | 2649 | CG | ASP | B | 434 | 47.425 | 51.113 | 49.196 | 1.00 | 43.54 | B | C |
| ATOM | 2650 | OD1 | ASP | B | 434 | 46.194 | 51.050 | 48.976 | 1.00 | 48.25 | B | O |
| ATOM | 2651 | OD2 | ASP | B | 434 | 48.236 | 51.552 | 48.347 | 1.00 | 45.56 | B | O |
| ATOM | 2652 | C | ASP | B | 434 | 46.354 | 52.154 | 51.739 | 1.00 | 26.13 | B | C |
| ATOM | 2653 | O | ASP | B | 434 | 47.094 | 53.143 | 51.730 | 1.00 | 25.98 | B | O |
| ATOM | 2654 | N | GLU | B | 435 | 45.028 | 52.248 | 51.826 | 1.00 | 20.35 | B | N |
| ATOM | 2655 | CA | GLU | B | 435 | 44.358 | 53.546 | 51.869 | 1.00 | 19.52 | B | C |
| ATOM | 2656 | CB | GLU | B | 435 | 42.842 | 53.356 | 51.809 | 1.00 | 17.59 | B | C |
| ATOM | 2657 | CG | GLU | B | 435 | 42.333 | 53.053 | 50.411 | 1.00 | 15.30 | B | C |
| ATOM | 2658 | CD | GLU | B | 435 | 40.830 | 52.906 | 50.347 | 1.00 | 15.49 | B | C |
| ATOM | 2659 | OE1 | GLU | B | 435 | 40.353 | 51.789 | 50.059 | 1.00 | 17.12 | B | O |
| ATOM | 2660 | OE2 | GLU | B | 435 | 40.119 | 53.906 | 50.577 | 1.00 | 17.74 | B | O |
| ATOM | 2661 | C | GLU | B | 435 | 44.720 | 54.384 | 53.092 | 1.00 | 21.05 | B | C |
| ATOM | 2662 | O | GLU | B | 435 | 44.888 | 55.602 | 53.003 | 1.00 | 22.18 | B | O |
| ATOM | 2663 | N | TRP | B | 436 | 44.843 | 53.727 | 54.237 | 1.00 | 23.57 | B | N |
| ATOM | 2664 | CA | TRP | B | 436 | 45.187 | 54.414 | 55.476 | 1.00 | 19.37 | B | C |
| ATOM | 2665 | CB | TRP | B | 436 | 45.036 | 53.450 | 56.658 | 1.00 | 20.01 | B | C |
| ATOM | 2666 | CG | TRP | B | 436 | 43.604 | 53.252 | 57.102 | 1.00 | 14.07 | B | C |
| ATOM | 2667 | CD2 | TRP | B | 436 | 42.826 | 54.145 | 57.910 | 1.00 | 12.48 | B | C |
| ATOM | 2668 | CE2 | TRP | B | 436 | 41.564 | 53.539 | 58.108 | 1.00 | 14.85 | B | C |
| ATOM | 2669 | CE3 | TRP | B | 436 | 43.074 | 55.398 | 58.487 | 1.00 | 12.36 | B | C |
| ATOM | 2670 | CD1 | TRP | B | 436 | 42.806 | 52.173 | 56.847 | 1.00 | 14.22 | B | C |
| ATOM | 2671 | NE1 | TRP | B | 436 | 41.575 | 52.337 | 57.450 | 1.00 | 13.04 | B | N |
| ATOM | 2672 | CZ2 | TRP | B | 436 | 40.554 | 54.145 | 58.864 | 1.00 | 13.52 | B | C |
| ATOM | 2673 | CZ3 | TRP | B | 436 | 42.069 | 56.000 | 59.241 | 1.00 | 11.84 | B | C |
| ATOM | 2674 | CH2 | TRP | B | 436 | 40.827 | 55.372 | 59.420 | 1.00 | 11.92 | B | C |
| ATOM | 2675 | C | TRP | B | 436 | 46.611 | 54.948 | 55.406 | 1.00 | 19.91 | B | C |
| ATOM | 2676 | O | TRP | B | 436 | 46.888 | 56.063 | 55.850 | 1.00 | 20.55 | B | O |
| ATOM | 2677 | N | SER | B | 437 | 47.514 | 54.151 | 54.842 | 1.00 | 20.89 | B | N |
| ATOM | 2678 | CA | SER | B | 437 | 48.905 | 54.559 | 54.719 | 1.00 | 20.50 | B | C |
| ATOM | 2679 | CB | SER | B | 437 | 49.745 | 53.419 | 54.155 | 1.00 | 21.79 | B | C |
| ATOM | 2680 | OG | SER | B | 437 | 50.939 | 53.932 | 53.587 | 1.00 | 29.30 | B | O |
| ATOM | 2681 | C | SER | B | 437 | 49.034 | 55.769 | 53.807 | 1.00 | 19.19 | B | C |
| ATOM | 2682 | O | SER | B | 437 | 49.859 | 56.651 | 54.041 | 1.00 | 21.36 | B | O |
| ATOM | 2683 | N | LYS | B | 438 | 48.219 | 55.808 | 52.759 | 1.00 | 19.39 | B | N |
| ATOM | 2684 | CA | LYS | B | 438 | 48.255 | 56.921 | 51.817 | 1.00 | 20.17 | B | C |
| ATOM | 2685 | CB | LYS | B | 438 | 47.503 | 56.556 | 50.538 | 1.00 | 23.04 | B | C |
| ATOM | 2686 | CG | LYS | B | 438 | 48.004 | 55.302 | 49.846 | 1.00 | 26.33 | B | C |
| ATOM | 2687 | CD | LYS | B | 438 | 48.222 | 55.555 | 48.364 | 1.00 | 29.03 | B | C |
| ATOM | 2688 | CE | LYS | B | 438 | 47.871 | 54.331 | 47.529 | 1.00 | 30.05 | B | C |
| ATOM | 2689 | NZ | LYS | B | 438 | 48.147 | 54.563 | 46.085 | 1.00 | 30.92 | B | N |
| ATOM | 2690 | C | LYS | B | 438 | 47.630 | 58.173 | 52.425 | 1.00 | 20.75 | B | C |
| ATOM | 2691 | O | LYS | B | 438 | 48.183 | 59.274 | 52.325 | 1.00 | 20.52 | B | O |
| ATOM | 2692 | N | LEU | B | 439 | 46.477 | 58.008 | 53.066 | 1.00 | 21.29 | B | N |
| ATOM | 2693 | CA | LEU | B | 439 | 45.801 | 59.147 | 53.675 | 1.00 | 18.45 | B | C |
| ATOM | 2694 | CB | LEU | B | 439 | 44.404 | 58.743 | 54.144 | 1.00 | 14.38 | B | C |
| ATOM | 2695 | CG | LEU | B | 439 | 43.449 | 59.876 | 54.532 | 1.00 | 14.91 | B | C |
| ATOM | 2696 | CD1 | LEU | B | 439 | 43.430 | 60.975 | 53.474 | 1.00 | 11.67 | B | C |
| ATOM | 2697 | CD2 | LEU | B | 439 | 42.061 | 59.284 | 54.718 | 1.00 | 12.30 | B | C |
| ATOM | 2698 | C | LEU | B | 439 | 46.604 | 59.726 | 54.834 | 1.00 | 19.31 | B | C |
| ATOM | 2699 | O | LEU | B | 439 | 46.737 | 60.942 | 54.944 | 1.00 | 22.75 | B | O |
| ATOM | 2700 | N | SER | B | 440 | 47.149 | 58.873 | 55.696 | 1.00 | 17.42 | B | N |
| ATOM | 2701 | CA | SER | B | 440 | 47.934 | 59.381 | 56.814 | 1.00 | 19.09 | B | C |
| ATOM | 2702 | CB | SER | B | 440 | 48.479 | 58.233 | 57.671 | 1.00 | 19.74 | B | C |
| ATOM | 2703 | OG | SER | B | 440 | 49.276 | 57.342 | 56.915 | 1.00 | 25.20 | B | O |
| ATOM | 2704 | C | SER | B | 440 | 49.080 | 60.221 | 56.273 | 1.00 | 20.04 | B | C |
| ATOM | 2705 | O | SER | B | 440 | 49.329 | 61.328 | 56.754 | 1.00 | 21.74 | B | O |
| ATOM | 2706 | N | SER | B | 441 | 49.762 | 59.707 | 55.255 | 1.00 | 22.48 | B | N |
| ATOM | 2707 | CA | SER | B | 441 | 50.891 | 60.421 | 54.648 | 1.00 | 22.41 | B | C |
| ATOM | 2708 | CB | SER | B | 441 | 51.575 | 59.537 | 53.600 | 1.00 | 23.34 | B | C |
| ATOM | 2709 | OG | SER | B | 441 | 51.861 | 58.249 | 54.117 | 1.00 | 25.11 | B | O |
| ATOM | 2710 | C | SER | B | 441 | 50.453 | 61.730 | 53.997 | 1.00 | 20.99 | B | C |
| ATOM | 2711 | O | SER | B | 441 | 51.172 | 62.732 | 54.051 | 1.00 | 21.21 | B | O |
| ATOM | 2712 | N | TRP | B | 442 | 49.275 | 61.723 | 53.381 | 1.00 | 19.84 | B | N |
| ATOM | 2713 | CA | TRP | B | 442 | 48.757 | 62.922 | 52.728 | 1.00 | 19.98 | B | C |
| ATOM | 2714 | CB | TRP | B | 442 | 47.453 | 62.587 | 51.988 | 1.00 | 18.06 | B | C |
| ATOM | 2715 | CG | TRP | B | 442 | 46.690 | 63.781 | 51.477 | 1.00 | 20.17 | B | C |
| ATOM | 2716 | CD2 | TRP | B | 442 | 45.588 | 64.443 | 52.120 | 1.00 | 22.97 | B | C |
| ATOM | 2717 | CE2 | TRP | B | 442 | 45.179 | 65.501 | 51.271 | 1.00 | 21.20 | B | C |
| ATOM | 2718 | CE3 | TRP | B | 442 | 44.905 | 64.246 | 53.329 | 1.00 | 20.64 | B | C |
| ATOM | 2719 | CD1 | TRP | B | 442 | 46.897 | 64.446 | 50.301 | 1.00 | 20.84 | B | C |
| ATOM | 2720 | NE1 | TRP | B | 442 | 45.994 | 65.481 | 50.171 | 1.00 | 20.10 | B | N |
| ATOM | 2721 | CZ2 | TRP | B | 442 | 44.121 | 66.359 | 51.596 | 1.00 | 19.60 | B | C |
| ATOM | 2722 | CZ3 | TRP | B | 442 | 43.852 | 65.101 | 53.647 | 1.00 | 19.43 | B | C |
| ATOM | 2723 | CH2 | TRP | B | 442 | 43.473 | 66.144 | 52.783 | 1.00 | 16.18 | B | C |
| ATOM | 2724 | C | TRP | B | 442 | 48.517 | 64.008 | 53.781 | 1.00 | 21.22 | B | C |
| ATOM | 2725 | O | TRP | B | 442 | 48.883 | 65.170 | 53.593 | 1.00 | 21.26 | B | O |
| ATOM | 2726 | N | PHE | B | 443 | 47.916 | 63.605 | 54.896 | 1.00 | 20.38 | B | N |
| ATOM | 2727 | CA | PHE | B | 443 | 47.591 | 64.505 | 55.997 | 1.00 | 21.03 | B | C |
| ATOM | 2728 | CB | PHE | B | 443 | 46.695 | 63.759 | 56.993 | 1.00 | 22.69 | B | C |
| ATOM | 2729 | CG | PHE | B | 443 | 46.066 | 64.640 | 58.033 | 1.00 | 23.79 | B | C |
| ATOM | 2730 | CD1 | PHE | B | 443 | 46.780 | 65.032 | 59.157 | 1.00 | 25.48 | B | C |
| ATOM | 2731 | CD2 | PHE | B | 443 | 44.751 | 65.063 | 57.896 | 1.00 | 25.56 | B | C |
| ATOM | 2732 | CE1 | PHE | B | 443 | 46.191 | 65.836 | 60.132 | 1.00 | 26.66 | B | C |
| ATOM | 2733 | CE2 | PHE | B | 443 | 44.153 | 65.866 | 58.865 | 1.00 | 26.16 | B | C |
| ATOM | 2734 | CZ | PHE | B | 443 | 44.875 | 66.252 | 59.984 | 1.00 | 24.10 | B | C |
| ATOM | 2735 | C | PHE | B | 443 | 48.821 | 65.060 | 56.719 | 1.00 | 21.44 | B | C |
| ATOM | 2736 | O | PHE | B | 443 | 48.916 | 66.262 | 56.969 | 1.00 | 19.50 | B | O |
| ATOM | 2737 | N | VAL | B | 444 | 49.755 | 64.178 | 57.065 | 1.00 | 20.67 | B | N |
| ATOM | 2738 | CA | VAL | B | 444 | 50.965 | 64.584 | 57.768 | 1.00 | 20.64 | B | C |
| ATOM | 2739 | CB | VAL | B | 444 | 51.729 | 63.354 | 58.292 | 1.00 | 23.02 | B | C |
| ATOM | 2740 | CG1 | VAL | B | 444 | 52.939 | 63.788 | 59.093 | 1.00 | 20.35 | B | C |
| ATOM | 2741 | CG2 | VAL | B | 444 | 50.809 | 62.499 | 59.143 | 1.00 | 25.45 | B | C |
| ATOM | 2742 | C | VAL | B | 444 | 51.906 | 65.395 | 56.885 | 1.00 | 23.99 | B | C |
| ATOM | 2743 | O | VAL | B | 444 | 52.336 | 66.488 | 57.253 | 1.00 | 23.62 | B | O |
| ATOM | 2744 | N | ARG | B | 445 | 52.222 | 64.854 | 55.715 | 1.00 | 26.32 | B | N |
| ATOM | 2745 | CA | ARG | B | 445 | 53.132 | 65.517 | 54.794 | 1.00 | 29.69 | B | C |
| ATOM | 2746 | CB | ARG | B | 445 | 53.367 | 64.637 | 53.568 | 1.00 | 33.19 | B | C |
| ATOM | 2747 | CG | ARG | B | 445 | 54.576 | 63.738 | 53.695 | 1.00 | 40.65 | B | C |
| ATOM | 2748 | CD | ARG | B | 445 | 54.372 | 62.452 | 52.930 | 1.00 | 42.99 | B | C |
| ATOM | 2749 | NE | ARG | B | 445 | 54.913 | 61.308 | 53.654 | 1.00 | 47.65 | B | N |
| ATOM | 2750 | CZ | ARG | B | 445 | 55.448 | 60.244 | 53.066 | 1.00 | 49.91 | B | C |
| ATOM | 2751 | NH1 | ARG | B | 445 | 55.514 | 60.180 | 51.740 | 1.00 | 50.52 | B | N |
| ATOM | 2752 | NH2 | ARG | B | 445 | 55.915 | 59.245 | 53.802 | 1.00 | 49.94 | B | N |
| ATOM | 2753 | C | ARG | B | 445 | 52.655 | 66.886 | 54.339 | 1.00 | 29.78 | B | C |
| ATOM | 2754 | O | ARG | B | 445 | 53.467 | 67.773 | 54.062 | 1.00 | 30.09 | B | O |
| ATOM | 2755 | N | ASN | B | 446 | 51.343 | 67.061 | 54.247 | 1.00 | 28.35 | B | N |
| ATOM | 2756 | CA | ASN | B | 446 | 50.802 | 68.339 | 53.807 | 1.00 | 26.64 | B | C |
| ATOM | 2757 | CB | ASN | B | 446 | 49.533 | 68.113 | 52.988 | 1.00 | 25.05 | B | C |
| ATOM | 2758 | CG | ASN | B | 446 | 49.834 | 67.709 | 51.552 | 1.00 | 24.89 | B | C |
| ATOM | 2759 | OD1 | ASN | B | 446 | 49.746 | 66.535 | 51.194 | 1.00 | 25.72 | B | O |
| ATOM | 2760 | ND2 | ASN | B | 446 | 50.190 | 68.685 | 50.722 | 1.00 | 24.44 | B | N |
| ATOM | 2761 | C | ASN | B | 446 | 50.525 | 69.256 | 54.994 | 1.00 | 26.12 | B | C |
| ATOM | 2762 | O | ASN | B | 446 | 50.089 | 70.394 | 54.823 | 1.00 | 24.63 | B | O |
| ATOM | 2763 | N | ARG | B | 447 | 50.799 | 68.754 | 56.195 | 1.00 | 25.96 | B | N |
| ATOM | 2764 | CA | ARG | B | 447 | 50.599 | 69.512 | 57.428 | 1.00 | 27.82 | B | C |
| ATOM | 2765 | CB | ARG | B | 447 | 51.614 | 70.656 | 57.528 | 1.00 | 29.71 | B | C |
| ATOM | 2766 | CG | ARG | B | 447 | 53.001 | 70.307 | 57.019 | 1.00 | 36.31 | B | C |
| ATOM | 2767 | CD | ARG | B | 447 | 53.931 | 69.916 | 58.158 | 1.00 | 39.85 | B | C |
| ATOM | 2768 | NE | ARG | B | 447 | 54.015 | 70.969 | 59.165 | 1.00 | 43.60 | B | N |
| ATOM | 2769 | CZ | ARG | B | 447 | 54.429 | 70.779 | 60.414 | 1.00 | 45.43 | B | C |
| ATOM | 2770 | NH1 | ARG | B | 447 | 54.803 | 69.572 | 60.820 | 1.00 | 45.27 | B | N |
| ATOM | 2771 | NH2 | ARG | B | 447 | 54.463 | 71.798 | 61.263 | 1.00 | 48.38 | B | N |
| ATOM | 2772 | C | ARG | B | 447 | 49.198 | 70.086 | 57.527 | 1.00 | 26.88 | B | C |
| ATOM | 2773 | O | ARG | B | 447 | 49.027 | 71.273 | 57.795 | 1.00 | 27.12 | B | O |
| ATOM | 2774 | N | ILE | B | 448 | 48.198 | 69.242 | 57.309 | 1.00 | 26.68 | B | N |
| ATOM | 2775 | CA | ILE | B | 448 | 46.818 | 69.686 | 57.381 | 1.00 | 28.90 | B | C |
| ATOM | 2776 | CB | ILE | B | 448 | 45.884 | 68.758 | 56.571 | 1.00 | 28.10 | B | C |
| ATOM | 2777 | CG2 | ILE | B | 448 | 44.429 | 69.033 | 56.923 | 1.00 | 27.61 | B | C |
| ATOM | 2778 | CG1 | ILE | B | 448 | 46.094 | 68.988 | 55.075 | 1.00 | 24.91 | B | C |
| ATOM | 2779 | CD1 | ILE | B | 448 | 46.245 | 67.723 | 54.308 | 1.00 | 27.49 | B | C |
| ATOM | 2780 | C | ILE | B | 448 | 46.394 | 69.686 | 58.838 | 1.00 | 29.12 | B | C |
| ATOM | 2781 | O | ILE | B | 448 | 46.138 | 68.641 | 59.422 | 1.00 | 32.75 | B | O |
| ATOM | 2782 | N | TYR | B | 449 | 46.350 | 70.866 | 59.432 | 1.00 | 28.02 | B | N |
| ATOM | 2783 | CA | TYR | B | 449 | 45.950 | 71.001 | 60.821 | 1.00 | 27.17 | B | C |
| ATOM | 2784 | CB | TYR | B | 449 | 47.098 | 70.635 | 61.776 | 1.00 | 28.30 | B | C |
| ATOM | 2785 | CG | TYR | B | 449 | 46.873 | 71.172 | 63.176 | 1.00 | 30.63 | B | C |
| ATOM | 2786 | CD1 | TYR | B | 449 | 46.081 | 70.477 | 64.093 | 1.00 | 30.15 | B | C |
| ATOM | 2787 | CE1 | TYR | B | 449 | 45.770 | 71.020 | 65.336 | 1.00 | 27.25 | B | C |
| ATOM | 2788 | CD2 | TYR | B | 449 | 47.360 | 72.424 | 63.550 | 1.00 | 31.70 | B | C |
| ATOM | 2789 | CE2 | TYR | B | 449 | 47.053 | 72.975 | 64.794 | 1.00 | 31.81 | B | C |
| ATOM | 2790 | CZ | TYR | B | 449 | 46.254 | 72.270 | 65.677 | 1.00 | 31.46 | B | C |
| ATOM | 2791 | OH | TYR | B | 449 | 45.917 | 72.833 | 66.888 | 1.00 | 33.67 | B | O |
| ATOM | 2792 | C | TYR | B | 449 | 45.565 | 72.450 | 61.026 | 1.00 | 26.39 | B | C |
| ATOM | 2793 | O | TYR | B | 449 | 46.383 | 73.348 | 60.858 | 1.00 | 26.42 | B | O |
| ATOM | 2794 | N | SER | B | 450 | 44.308 | 72.676 | 61.371 | 1.00 | 24.68 | B | N |
| ATOM | 2795 | CA | SER | B | 450 | 43.824 | 74.023 | 61.595 | 1.00 | 22.22 | B | C |
| ATOM | 2796 | CB | SER | B | 450 | 42.736 | 74.372 | 60.569 | 1.00 | 19.15 | B | C |
| ATOM | 2797 | OG | SER | B | 450 | 42.021 | 75.544 | 60.933 | 1.00 | 16.69 | B | O |
| ATOM | 2798 | C | SER | B | 450 | 43.256 | 74.024 | 63.003 | 1.00 | 23.42 | B | C |
| ATOM | 2799 | O | SER | B | 450 | 42.672 | 73.032 | 63.449 | 1.00 | 25.41 | B | O |
| ATOM | 2800 | N | SER | B | 451 | 43.437 | 75.126 | 63.713 | 1.00 | 22.85 | B | N |
| ATOM | 2801 | CA | SER | B | 451 | 42.928 | 75.206 | 65.067 | 1.00 | 25.20 | B | C |
| ATOM | 2802 | CB | SER | B | 451 | 43.521 | 76.414 | 65.776 | 1.00 | 23.53 | B | C |
| ATOM | 2803 | OG | SER | B | 451 | 43.099 | 77.593 | 65.128 | 1.00 | 27.10 | B | O |
| ATOM | 2804 | C | SER | B | 451 | 41.407 | 75.303 | 65.054 | 1.00 | 23.53 | B | C |
| ATOM | 2805 | O | SER | B | 451 | 40.772 | 75.254 | 66.107 | 1.00 | 26.09 | B | O |
| ATOM | 2806 | N | ASN | B | 452 | 40.828 | 75.432 | 63.862 | 1.00 | 21.07 | B | N |
| ATOM | 2807 | CA | ASN | B | 452 | 39.377 | 75.529 | 63.705 | 1.00 | 17.44 | B | C |
| ATOM | 2808 | CB | ASN | B | 452 | 39.009 | 76.832 | 63.014 | 1.00 | 17.03 | B | C |
| ATOM | 2809 | CG | ASN | B | 452 | 39.046 | 78.003 | 63.948 | 1.00 | 18.87 | B | C |
| ATOM | 2810 | OD1 | ASN | B | 452 | 40.113 | 78.414 | 64.394 | 1.00 | 22.52 | B | O |
| ATOM | 2811 | ND2 | ASN | B | 452 | 37.881 | 78.558 | 64.255 | 1.00 | 17.45 | B | N |
| ATOM | 2812 | C | ASN | B | 452 | 38.751 | 74.372 | 62.922 | 1.00 | 15.31 | B | C |
| ATOM | 2813 | O | ASN | B | 452 | 37.623 | 74.490 | 62.443 | 1.00 | 11.38 | B | O |
| ATOM | 2814 | N | MET | B | 453 | 39.481 | 73.267 | 62.794 | 1.00 | 11.52 | B | N |
| ATOM | 2815 | CA | MET | B | 453 | 38.982 | 72.102 | 62.085 | 1.00 | 11.25 | B | C |
| ATOM | 2816 | CB | MET | B | 453 | 39.583 | 72.040 | 60.679 | 1.00 | 13.09 | B | C |
| ATOM | 2817 | CG | MET | B | 453 | 38.884 | 72.885 | 59.639 | 1.00 | 16.40 | B | C |
| ATOM | 2818 | SD | MET | B | 453 | 39.605 | 72.680 | 57.990 | 1.00 | 21.99 | B | S |
| ATOM | 2819 | CE | MET | B | 453 | 38.253 | 73.259 | 56.949 | 1.00 | 16.92 | B | C |
| ATOM | 2820 | C | MET | B | 453 | 39.371 | 70.829 | 62.829 | 1.00 | 13.71 | B | C |
| ATOM | 2821 | O | MET | B | 453 | 40.491 | 70.727 | 63.325 | 1.00 | 14.49 | B | O |
| ATOM | 2822 | N | THR | B | 454 | 38.438 | 69.879 | 62.931 | 1.00 | 12.99 | B | N |
| ATOM | 2823 | CA | THR | B | 454 | 38.705 | 68.585 | 63.554 | 1.00 | 11.96 | B | C |
| ATOM | 2824 | CB | THR | B | 454 | 37.924 | 68.348 | 64.885 | 1.00 | 11.94 | B | C |
| ATOM | 2825 | OG1 | THR | B | 454 | 36.592 | 68.862 | 64.791 | 1.00 | 17.85 | B | O |
| ATOM | 2826 | CG2 | THR | B | 454 | 38.641 | 69.035 | 66.030 | 1.00 | 6.82 | B | C |
| ATOM | 2827 | C | THR | B | 454 | 38.260 | 67.606 | 62.480 | 1.00 | 14.25 | B | C |
| ATOM | 2828 | O | THR | B | 454 | 37.414 | 67.942 | 61.656 | 1.00 | 16.06 | B | O |
| ATOM | 2829 | N | TRP | B | 455 | 38.813 | 66.399 | 62.490 | 1.00 | 15.95 | B | N |
| ATOM | 2830 | CA | TRP | B | 455 | 38.529 | 65.436 | 61.437 | 1.00 | 15.83 | B | C |
| ATOM | 2831 | CB | TRP | B | 455 | 39.834 | 65.166 | 60.679 | 1.00 | 16.25 | B | C |
| ATOM | 2832 | CG | TRP | B | 455 | 40.462 | 66.417 | 60.149 | 1.00 | 13.49 | B | C |
| ATOM | 2833 | CD2 | TRP | B | 455 | 40.290 | 66.965 | 58.841 | 1.00 | 16.62 | B | C |
| ATOM | 2834 | CE2 | TRP | B | 455 | 41.014 | 68.178 | 58.795 | 1.00 | 16.37 | B | C |
| ATOM | 2835 | CE3 | TRP | B | 455 | 39.590 | 66.550 | 57.699 | 1.00 | 17.17 | B | C |
| ATOM | 2836 | CD1 | TRP | B | 455 | 41.264 | 67.287 | 60.826 | 1.00 | 12.32 | B | C |
| ATOM | 2837 | NE1 | TRP | B | 455 | 41.603 | 68.351 | 60.020 | 1.00 | 11.42 | B | N |
| ATOM | 2838 | CZ2 | TRP | B | 455 | 41.062 | 68.978 | 57.652 | 1.00 | 16.61 | B | C |
| ATOM | 2839 | CZ3 | TRP | B | 455 | 39.637 | 67.348 | 56.563 | 1.00 | 20.12 | B | C |
| ATOM | 2840 | CH2 | TRP | B | 455 | 40.368 | 68.549 | 56.550 | 1.00 | 17.00 | B | C |
| ATOM | 2841 | C | TRP | B | 455 | 37.881 | 64.106 | 61.787 | 1.00 | 17.65 | B | C |
| ATOM | 2842 | O | TRP | B | 455 | 38.039 | 63.591 | 62.892 | 1.00 | 18.53 | B | O |
| ATOM | 2843 | N | MET | B | 456 | 37.168 | 63.556 | 60.803 | 1.00 | 15.39 | B | N |
| ATOM | 2844 | CA | MET | B | 456 | 36.488 | 62.273 | 60.915 | 1.00 | 15.64 | B | C |
| ATOM | 2845 | CB | MET | B | 456 | 34.989 | 62.476 | 61.118 | 1.00 | 16.76 | B | C |
| ATOM | 2846 | CG | MET | B | 456 | 34.628 | 63.281 | 62.343 | 1.00 | 14.55 | B | C |
| ATOM | 2847 | SD | MET | B | 456 | 32.849 | 63.477 | 62.516 | 1.00 | 16.21 | B | S |
| ATOM | 2848 | CE | MET | B | 456 | 32.262 | 61.831 | 62.126 | 1.00 | 16.88 | B | C |
| ATOM | 2849 | C | MET | B | 456 | 36.698 | 61.493 | 59.623 | 1.00 | 16.45 | B | C |
| ATOM | 2850 | O | MET | B | 456 | 37.148 | 62.046 | 58.623 | 1.00 | 16.10 | B | O |
| ATOM | 2851 | N | ILE | B | 457 | 36.370 | 60.205 | 59.646 | 1.00 | 18.30 | B | N |
| ATOM | 2852 | CA | ILE | B | 457 | 36.501 | 59.368 | 58.461 | 1.00 | 16.52 | B | C |
| ATOM | 2853 | CB | ILE | B | 457 | 37.466 | 58.185 | 58.698 | 1.00 | 16.80 | B | C |
| ATOM | 2854 | CG2 | ILE | B | 457 | 37.080 | 56.995 | 57.832 | 1.00 | 12.48 | B | C |
| ATOM | 2855 | CG1 | ILE | B | 457 | 38.882 | 58.596 | 58.306 | 1.00 | 17.07 | B | C |
| ATOM | 2856 | CD1 | ILE | B | 457 | 39.825 | 58.620 | 59.446 | 1.00 | 18.44 | B | C |
| ATOM | 2857 | C | ILE | B | 457 | 35.133 | 58.831 | 58.074 | 1.00 | 16.13 | B | C |
| ATOM | 2858 | O | ILE | B | 457 | 34.340 | 58.438 | 58.930 | 1.00 | 16.42 | B | O |
| ATOM | 2859 | N | GLN | B | 458 | 34.852 | 58.830 | 56.777 | 1.00 | 17.49 | B | N |
| ATOM | 2860 | CA | GLN | B | 458 | 33.576 | 58.336 | 56.275 | 1.00 | 15.88 | B | C |
| ATOM | 2861 | CB | GLN | B | 458 | 32.839 | 59.439 | 55.522 | 1.00 | 15.22 | B | C |
| ATOM | 2862 | CG | GLN | B | 458 | 33.642 | 60.018 | 54.367 | 1.00 | 19.36 | B | C |
| ATOM | 2863 | CD | GLN | B | 458 | 32.888 | 61.092 | 53.584 | 1.00 | 23.83 | B | C |
| ATOM | 2864 | OE1 | GLN | B | 458 | 31.960 | 61.722 | 54.096 | 1.00 | 25.49 | B | O |
| ATOM | 2865 | NE2 | GLN | B | 458 | 33.291 | 61.303 | 52.336 | 1.00 | 23.06 | B | N |
| ATOM | 2866 | C | GLN | B | 458 | 33.842 | 57.183 | 55.330 | 1.00 | 15.05 | B | C |
| ATOM | 2867 | O | GLN | B | 458 | 34.803 | 57.210 | 54.559 | 1.00 | 14.09 | B | O |
| ATOM | 2868 | N | VAL | B | 459 | 33.012 | 56.156 | 55.412 | 1.00 | 12.73 | B | N |
| ATOM | 2869 | CA | VAL | B | 459 | 33.160 | 55.036 | 54.518 | 1.00 | 15.74 | B | C |
| ATOM | 2870 | CB | VAL | B | 459 | 33.603 | 53.733 | 55.273 | 1.00 | 17.39 | B | C |
| ATOM | 2871 | CG1 | VAL | B | 459 | 33.865 | 54.039 | 56.723 | 1.00 | 17.45 | B | C |
| ATOM | 2872 | CG2 | VAL | B | 459 | 32.583 | 52.617 | 55.107 | 1.00 | 18.94 | B | C |
| ATOM | 2873 | C | VAL | B | 459 | 31.825 | 54.889 | 53.802 | 1.00 | 15.34 | B | C |
| ATOM | 2874 | O | VAL | B | 459 | 30.817 | 54.505 | 54.397 | 1.00 | 16.90 | B | O |
| ATOM | 2875 | N | PRO | B | 460 | 31.789 | 55.275 | 52.515 | 1.00 | 16.83 | B | N |
| ATOM | 2876 | CD | PRO | B | 460 | 32.900 | 55.862 | 51.739 | 1.00 | 13.37 | B | C |
| ATOM | 2877 | CA | PRO | B | 460 | 30.560 | 55.178 | 51.723 | 1.00 | 14.61 | B | C |
| ATOM | 2878 | CB | PRO | B | 460 | 30.956 | 55.769 | 50.370 | 1.00 | 15.52 | B | C |
| ATOM | 2879 | CG | PRO | B | 460 | 32.190 | 56.600 | 50.657 | 1.00 | 12.68 | B | C |
| ATOM | 2880 | C | PRO | B | 460 | 30.107 | 53.729 | 51.617 | 1.00 | 16.05 | B | C |
| ATOM | 2881 | O | PRO | B | 460 | 30.932 | 52.828 | 51.510 | 1.00 | 18.92 | B | O |
| ATOM | 2882 | N | ARG | B | 461 | 28.800 | 53.508 | 51.659 | 1.00 | 15.18 | B | N |
| ATOM | 2883 | CA | ARG | B | 461 | 28.260 | 52.161 | 51.569 | 1.00 | 19.68 | B | C |
| ATOM | 2884 | CB | ARG | B | 461 | 26.913 | 52.082 | 52.298 | 1.00 | 17.00 | B | C |
| ATOM | 2885 | CG | ARG | B | 461 | 26.937 | 52.649 | 53.713 | 1.00 | 14.29 | B | C |
| ATOM | 2886 | CD | ARG | B | 461 | 25.662 | 52.317 | 54.485 | 1.00 | 12.91 | B | C |
| ATOM | 2887 | NE | ARG | B | 461 | 24.501 | 53.029 | 53.960 | 1.00 | 14.12 | B | N |
| ATOM | 2888 | CZ | ARG | B | 461 | 24.218 | 54.300 | 54.227 | 1.00 | 13.35 | B | C |
| ATOM | 2889 | NH1 | ARG | B | 461 | 25.007 | 55.006 | 55.014 | 1.00 | 17.32 | B | N |
| ATOM | 2890 | NH2 | ARG | B | 461 | 23.156 | 54.877 | 53.687 | 1.00 | 15.83 | B | N |
| ATOM | 2891 | C | ARG | B | 461 | 28.092 | 51.768 | 50.105 | 1.00 | 21.60 | B | C |
| ATOM | 2892 | O | ARG | B | 461 | 26.969 | 51.663 | 49.596 | 1.00 | 22.40 | B | O |
| ATOM | 2893 | N | ILE | B | 462 | 29.216 | 51.550 | 49.426 | 1.00 | 22.31 | B | N |
| ATOM | 2894 | CA | ILE | B | 462 | 29.187 | 51.178 | 48.014 | 1.00 | 20.66 | B | C |
| ATOM | 2895 | CB | ILE | B | 462 | 29.777 | 52.310 | 47.138 | 1.00 | 19.83 | B | C |
| ATOM | 2896 | CG2 | ILE | B | 462 | 28.952 | 53.593 | 47.319 | 1.00 | 11.83 | B | C |
| ATOM | 2897 | CG1 | ILE | B | 462 | 31.243 | 52.549 | 47.509 | 1.00 | 15.41 | B | C |
| ATOM | 2898 | CD1 | ILE | B | 462 | 31.901 | 53.651 | 46.708 | 1.00 | 11.03 | B | C |
| ATOM | 2899 | C | ILE | B | 462 | 29.934 | 49.875 | 47.736 | 1.00 | 20.28 | B | C |
| ATOM | 2900 | O | ILE | B | 462 | 30.676 | 49.769 | 46.763 | 1.00 | 21.42 | B | O |
| ATOM | 2901 | N | TYR | B | 463 | 29.732 | 48.885 | 48.599 | 1.00 | 20.88 | B | N |
| ATOM | 2902 | CA | TYR | B | 463 | 30.384 | 47.598 | 48.432 | 1.00 | 22.10 | B | C |
| ATOM | 2903 | CB | TYR | B | 463 | 29.964 | 46.633 | 49.548 | 1.00 | 19.19 | B | C |
| ATOM | 2904 | CG | TYR | B | 463 | 30.112 | 45.170 | 49.179 | 1.00 | 18.27 | B | C |
| ATOM | 2905 | CD1 | TYR | B | 463 | 31.322 | 44.497 | 49.372 | 1.00 | 18.03 | B | C |
| ATOM | 2906 | CE1 | TYR | B | 463 | 31.470 | 43.157 | 49.008 | 1.00 | 18.61 | B | C |
| ATOM | 2907 | CD2 | TYR | B | 463 | 29.049 | 44.466 | 48.617 | 1.00 | 15.97 | B | C |
| ATOM | 2908 | CE2 | TYR | B | 463 | 29.185 | 43.125 | 48.250 | 1.00 | 18.74 | B | C |
| ATOM | 2909 | CZ | TYR | B | 463 | 30.396 | 42.479 | 48.447 | 1.00 | 18.96 | B | C |
| ATOM | 2910 | OH | TYR | B | 463 | 30.526 | 41.161 | 48.076 | 1.00 | 19.54 | B | O |
| ATOM | 2911 | C | TYR | B | 463 | 29.991 | 47.016 | 47.080 | 1.00 | 24.65 | B | C |
| ATOM | 2912 | O | TYR | B | 463 | 30.836 | 46.513 | 46.337 | 1.00 | 26.23 | B | O |
| ATOM | 2913 | N | ASP | B | 464 | 28.701 | 47.092 | 46.767 | 1.00 | 24.99 | B | N |
| ATOM | 2914 | CA | ASP | B | 464 | 28.182 | 46.563 | 45.509 | 1.00 | 25.61 | B | C |
| ATOM | 2915 | CB | ASP | B | 464 | 26.689 | 46.901 | 45.369 | 1.00 | 25.28 | B | C |
| ATOM | 2916 | CG | ASP | B | 464 | 26.394 | 48.384 | 45.563 | 1.00 | 29.98 | B | C |
| ATOM | 2917 | OD1 | ASP | B | 464 | 25.272 | 48.818 | 45.232 | 1.00 | 31.55 | B | O |
| ATOM | 2918 | OD2 | ASP | B | 464 | 27.272 | 49.126 | 46.044 | 1.00 | 33.50 | B | O |
| ATOM | 2919 | C | ASP | B | 464 | 28.958 | 47.075 | 44.292 | 1.00 | 24.64 | B | C |
| ATOM | 2920 | O | ASP | B | 464 | 29.131 | 46.358 | 43.313 | 1.00 | 24.06 | B | O |
| ATOM | 2921 | N | VAL | B | 465 | 29.441 | 48.308 | 44.362 | 1.00 | 24.96 | B | N |
| ATOM | 2922 | CA | VAL | B | 465 | 30.191 | 48.889 | 43.257 | 1.00 | 25.55 | B | C |
| ATOM | 2923 | CB | VAL | B | 465 | 30.351 | 50.414 | 43.440 | 1.00 | 22.61 | B | C |
| ATOM | 2924 | CG1 | VAL | B | 465 | 31.323 | 50.972 | 42.421 | 1.00 | 19.34 | B | C |
| ATOM | 2925 | CG2 | VAL | B | 465 | 29.008 | 51.085 | 43.298 | 1.00 | 22.28 | B | C |
| ATOM | 2926 | C | VAL | B | 465 | 31.575 | 48.254 | 43.136 | 1.00 | 29.40 | B | C |
| ATOM | 2927 | O | VAL | B | 465 | 31.999 | 47.878 | 42.038 | 1.00 | 30.93 | B | O |
| ATOM | 2928 | N | PHE | B | 466 | 32.273 | 48.138 | 44.263 | 1.00 | 27.48 | B | N |
| ATOM | 2929 | CA | PHE | B | 466 | 33.611 | 47.553 | 44.284 | 1.00 | 28.35 | B | C |
| ATOM | 2930 | CB | PHE | B | 466 | 34.268 | 47.753 | 45.659 | 1.00 | 27.77 | B | C |
| ATOM | 2931 | CG | PHE | B | 466 | 34.584 | 49.186 | 45.978 | 1.00 | 27.13 | B | C |
| ATOM | 2932 | CD1 | PHE | B | 466 | 35.074 | 50.038 | 44.996 | 1.00 | 27.88 | B | C |
| ATOM | 2933 | CD2 | PHE | B | 466 | 34.365 | 49.693 | 47.251 | 1.00 | 29.37 | B | C |
| ATOM | 2934 | CE1 | PHE | B | 466 | 35.339 | 51.378 | 45.275 | 1.00 | 26.02 | B | C |
| ATOM | 2935 | CE2 | PHE | B | 466 | 34.626 | 51.029 | 47.542 | 1.00 | 28.45 | B | C |
| ATOM | 2936 | CZ | PHE | B | 466 | 35.113 | 51.874 | 46.547 | 1.00 | 26.82 | B | C |
| ATOM | 2937 | C | PHE | B | 466 | 33.563 | 46.065 | 43.964 | 1.00 | 27.67 | B | C |
| ATOM | 2938 | O | PHE | B | 466 | 34.468 | 45.528 | 43.334 | 1.00 | 27.07 | B | O |
| ATOM | 2939 | N | ARG | B | 467 | 32.499 | 45.405 | 44.403 | 1.00 | 27.62 | B | N |
| ATOM | 2940 | CA | ARG | B | 467 | 32.336 | 43.980 | 44.171 | 1.00 | 27.51 | B | C |
| ATOM | 2941 | CB | ARG | B | 467 | 31.178 | 43.454 | 45.013 | 1.00 | 26.69 | B | C |
| ATOM | 2942 | CG | ARG | B | 467 | 30.838 | 42.005 | 44.748 | 1.00 | 25.98 | B | C |
| ATOM | 2943 | CD | ARG | B | 467 | 31.962 | 41.090 | 45.187 | 1.00 | 30.63 | B | C |
| ATOM | 2944 | NE | ARG | B | 467 | 31.661 | 39.710 | 44.835 | 1.00 | 35.61 | B | N |
| ATOM | 2945 | CZ | ARG | B | 467 | 31.628 | 39.252 | 43.589 | 1.00 | 36.76 | B | C |
| ATOM | 2946 | NH1 | ARG | B | 467 | 31.881 | 40.069 | 42.577 | 1.00 | 39.22 | B | N |
| ATOM | 2947 | NH2 | ARG | B | 467 | 31.320 | 37.985 | 43.354 | 1.00 | 39.34 | B | N |
| ATOM | 2948 | C | ARG | B | 467 | 32.092 | 43.636 | 42.701 | 1.00 | 29.55 | B | C |
| ATOM | 2949 | O | ARG | B | 467 | 32.632 | 42.653 | 42.190 | 1.00 | 30.33 | B | O |
| ATOM | 2950 | N | SER | B | 468 | 31.277 | 44.440 | 42.023 | 1.00 | 29.61 | B | N |
| ATOM | 2951 | CA | SER | B | 468 | 30.965 | 44.196 | 40.619 | 1.00 | 27.38 | B | C |
| ATOM | 2952 | CB | SER | B | 468 | 29.784 | 45.063 | 40.183 | 1.00 | 25.88 | B | C |
| ATOM | 2953 | OG | SER | B | 468 | 29.986 | 46.412 | 40.560 | 1.00 | 30.66 | B | O |
| ATOM | 2954 | C | SER | B | 468 | 32.176 | 44.463 | 39.733 | 1.00 | 27.88 | B | C |
| ATOM | 2955 | O | SER | B | 468 | 32.245 | 43.978 | 38.606 | 1.00 | 30.26 | B | O |
| ATOM | 2956 | N | LYS | B | 469 | 33.125 | 45.236 | 40.252 | 1.00 | 27.64 | B | N |
| ATOM | 2957 | CA | LYS | B | 469 | 34.355 | 45.564 | 39.534 | 1.00 | 27.72 | B | C |
| ATOM | 2958 | CB | LYS | B | 469 | 34.824 | 46.972 | 39.898 | 1.00 | 29.53 | B | C |
| ATOM | 2959 | CG | LYS | B | 469 | 34.321 | 48.074 | 38.990 | 1.00 | 34.21 | B | C |
| ATOM | 2960 | CD | LYS | B | 469 | 34.846 | 49.428 | 39.452 | 1.00 | 39.69 | B | C |
| ATOM | 2961 | CE | LYS | B | 469 | 34.289 | 50.568 | 38.598 | 1.00 | 45.54 | B | C |
| ATOM | 2962 | NZ | LYS | B | 469 | 32.804 | 50.666 | 38.690 | 1.00 | 45.49 | B | N |
| ATOM | 2963 | C | LYS | B | 469 | 35.423 | 44.561 | 39.965 | 1.00 | 27.79 | B | C |
| ATOM | 2964 | O | LYS | B | 469 | 36.595 | 44.672 | 39.598 | 1.00 | 25.09 | B | O |
| ATOM | 2965 | N | ASN | B | 470 | 35.005 | 43.587 | 40.762 | 1.00 | 28.04 | B | N |
| ATOM | 2966 | CA | ASN | B | 470 | 35.905 | 42.565 | 41.259 | 1.00 | 27.69 | B | C |
| ATOM | 2967 | CB | ASN | B | 470 | 36.346 | 41.681 | 40.106 | 1.00 | 28.64 | B | C |
| ATOM | 2968 | CG | ASN | B | 470 | 35.202 | 40.862 | 39.553 | 1.00 | 31.15 | B | C |
| ATOM | 2969 | OD1 | ASN | B | 470 | 34.672 | 39.982 | 40.234 | 1.00 | 30.85 | B | O |
| ATOM | 2970 | ND2 | ASN | B | 470 | 34.804 | 41.152 | 38.316 | 1.00 | 31.91 | B | N |
| ATOM | 2971 | C | ASN | B | 470 | 37.104 | 43.161 | 41.986 | 1.00 | 29.29 | B | C |
| ATOM | 2972 | O | ASN | B | 470 | 38.223 | 42.662 | 41.897 | 1.00 | 27.56 | B | O |
| ATOM | 2973 | N | PHE | B | 471 | 36.850 | 44.245 | 42.710 | 1.00 | 30.86 | B | N |
| ATOM | 2974 | CA | PHE | B | 471 | 37.871 | 44.914 | 43.501 | 1.00 | 31.39 | B | C |
| ATOM | 2975 | CB | PHE | B | 471 | 37.509 | 46.382 | 43.696 | 1.00 | 31.26 | B | C |
| ATOM | 2976 | CG | PHE | B | 471 | 37.993 | 47.283 | 42.601 | 1.00 | 34.24 | B | C |
| ATOM | 2977 | CD1 | PHE | B | 471 | 38.728 | 46.780 | 41.532 | 1.00 | 35.17 | B | C |
| ATOM | 2978 | CD2 | PHE | B | 471 | 37.721 | 48.646 | 42.643 | 1.00 | 35.43 | B | C |
| ATOM | 2979 | CE1 | PHE | B | 471 | 39.189 | 47.623 | 40.522 | 1.00 | 33.84 | B | C |
| ATOM | 2980 | CE2 | PHE | B | 471 | 38.176 | 49.500 | 41.638 | 1.00 | 36.65 | B | C |
| ATOM | 2981 | CZ | PHE | B | 471 | 38.913 | 48.986 | 40.576 | 1.00 | 35.71 | B | C |
| ATOM | 2982 | C | PHE | B | 471 | 37.910 | 44.219 | 44.863 | 1.00 | 32.32 | B | C |
| ATOM | 2983 | O | PHE | B | 471 | 38.875 | 44.360 | 45.620 | 1.00 | 32.30 | B | O |
| ATOM | 2984 | N | LEU | B | 472 | 36.849 | 43.469 | 45.160 | 1.00 | 28.54 | B | N |
| ATOM | 2985 | CA | LEU | B | 472 | 36.731 | 42.741 | 46.420 | 1.00 | 27.96 | B | C |
| ATOM | 2986 | CB | LEU | B | 472 | 35.944 | 43.562 | 47.452 | 1.00 | 26.86 | B | C |
| ATOM | 2987 | CG | LEU | B | 472 | 36.362 | 45.015 | 47.692 | 1.00 | 27.00 | B | C |
| ATOM | 2988 | CD1 | LEU | B | 472 | 35.208 | 45.808 | 48.280 | 1.00 | 23.80 | B | C |
| ATOM | 2989 | CD2 | LEU | B | 472 | 37.551 | 45.040 | 48.626 | 1.00 | 28.22 | B | C |
| ATOM | 2990 | C | LEU | B | 472 | 36.016 | 41.412 | 46.209 | 1.00 | 27.19 | B | C |
| ATOM | 2991 | O | LEU | B | 472 | 35.130 | 41.304 | 45.364 | 1.00 | 27.02 | B | O |
| ATOM | 2992 | N | PRO | B | 473 | 36.393 | 40.380 | 46.980 | 1.00 | 26.30 | B | N |
| ATOM | 2993 | CD | PRO | B | 473 | 37.464 | 40.378 | 47.996 | 1.00 | 22.68 | B | C |
| ATOM | 2994 | CA | PRO | B | 473 | 35.757 | 39.067 | 46.847 | 1.00 | 24.97 | B | C |
| ATOM | 2995 | CB | PRO | B | 473 | 36.816 | 38.108 | 47.368 | 1.00 | 25.12 | B | C |
| ATOM | 2996 | CG | PRO | B | 473 | 37.578 | 38.925 | 48.386 | 1.00 | 25.39 | B | C |
| ATOM | 2997 | C | PRO | B | 473 | 34.459 | 38.949 | 47.634 | 1.00 | 25.40 | B | C |
| ATOM | 2998 | O | PRO | B | 473 | 33.572 | 38.170 | 47.271 | 1.00 | 26.25 | B | O |
| ATOM | 2999 | N | HIS | B | 474 | 34.356 | 39.721 | 48.714 | 1.00 | 24.21 | B | N |
| ATOM | 3000 | CA | HIS | B | 474 | 33.177 | 39.698 | 49.583 | 1.00 | 24.30 | B | C |
| ATOM | 3001 | CB | HIS | B | 474 | 33.181 | 38.413 | 50.409 | 1.00 | 21.79 | B | C |
| ATOM | 3002 | CG | HIS | B | 474 | 34.458 | 38.196 | 51.158 | 1.00 | 23.50 | B | C |
| ATOM | 3003 | CD2 | HIS | B | 474 | 35.138 | 39.001 | 52.008 | 1.00 | 22.87 | B | C |
| ATOM | 3004 | ND1 | HIS | B | 474 | 35.209 | 37.047 | 51.037 | 1.00 | 23.92 | B | N |
| ATOM | 3005 | CE1 | HIS | B | 474 | 36.296 | 37.153 | 51.780 | 1.00 | 21.83 | B | C |
| ATOM | 3006 | NE2 | HIS | B | 474 | 36.278 | 38.330 | 52.380 | 1.00 | 22.73 | B | N |
| ATOM | 3007 | C | HIS | B | 474 | 33.204 | 40.910 | 50.523 | 1.00 | 23.59 | B | C |
| ATOM | 3008 | O | HIS | B | 474 | 34.146 | 41.701 | 50.490 | 1.00 | 23.22 | B | O |
| ATOM | 3009 | N | PHE | B | 475 | 32.183 | 41.039 | 51.369 | 1.00 | 24.36 | B | N |
| ATOM | 3010 | CA | PHE | B | 475 | 32.080 | 42.160 | 52.314 | 1.00 | 22.57 | B | C |
| ATOM | 3011 | CB | PHE | B | 475 | 30.681 | 42.204 | 52.931 | 1.00 | 18.65 | B | C |
| ATOM | 3012 | CG | PHE | B | 475 | 30.380 | 43.473 | 53.679 | 1.00 | 19.34 | B | C |
| ATOM | 3013 | CD1 | PHE | B | 475 | 30.142 | 43.445 | 55.053 | 1.00 | 20.96 | B | C |
| ATOM | 3014 | CD2 | PHE | B | 475 | 30.292 | 44.692 | 53.013 | 1.00 | 20.17 | B | C |
| ATOM | 3015 | CE1 | PHE | B | 475 | 29.819 | 44.608 | 55.751 | 1.00 | 16.41 | B | C |
| ATOM | 3016 | CE2 | PHE | B | 475 | 29.970 | 45.863 | 53.699 | 1.00 | 16.77 | B | C |
| ATOM | 3017 | CZ | PHE | B | 475 | 29.733 | 45.818 | 55.075 | 1.00 | 16.91 | B | C |
| ATOM | 3018 | C | PHE | B | 475 | 33.119 | 42.091 | 53.432 | 1.00 | 21.32 | B | C |
| ATOM | 3019 | O | PHE | B | 475 | 33.616 | 43.124 | 53.899 | 1.00 | 22.61 | B | O |
| ATOM | 3020 | N | GLY | B | 476 | 33.446 | 40.876 | 53.856 | 1.00 | 19.06 | B | N |
| ATOM | 3021 | CA | GLY | B | 476 | 34.428 | 40.703 | 54.912 | 1.00 | 17.35 | B | C |
| ATOM | 3022 | C | GLY | B | 476 | 35.758 | 41.361 | 54.601 | 1.00 | 17.62 | B | C |
| ATOM | 3023 | O | GLY | B | 476 | 36.435 | 41.857 | 55.504 | 1.00 | 18.50 | B | O |
| ATOM | 3024 | N | LYS | B | 477 | 36.134 | 41.385 | 53.326 | 1.00 | 17.07 | B | N |
| ATOM | 3025 | CA | LYS | B | 477 | 37.400 | 41.985 | 52.931 | 1.00 | 18.01 | B | C |
| ATOM | 3026 | CB | LYS | B | 477 | 37.843 | 41.456 | 51.565 | 1.00 | 20.00 | B | C |
| ATOM | 3027 | CG | LYS | B | 477 | 39.134 | 42.074 | 51.052 | 1.00 | 22.26 | B | C |
| ATOM | 3028 | CD | LYS | B | 477 | 40.375 | 41.452 | 51.683 | 1.00 | 25.99 | B | C |
| ATOM | 3029 | CE | LYS | B | 477 | 41.612 | 42.296 | 51.381 | 1.00 | 26.67 | B | C |
| ATOM | 3030 | NZ | LYS | B | 477 | 42.830 | 41.775 | 52.057 | 1.00 | 30.57 | B | N |
| ATOM | 3031 | C | LYS | B | 477 | 37.318 | 43.501 | 52.902 | 1.00 | 18.26 | B | C |
| ATOM | 3032 | O | LYS | B | 477 | 38.345 | 44.186 | 52.919 | 1.00 | 19.93 | B | O |
| ATOM | 3033 | N | MET | B | 478 | 36.103 | 44.034 | 52.849 | 1.00 | 17.45 | B | N |
| ATOM | 3034 | CA | MET | B | 478 | 35.936 | 45.484 | 52.848 | 1.00 | 19.91 | B | C |
| ATOM | 3035 | CB | MET | B | 478 | 34.548 | 45.883 | 52.355 | 1.00 | 18.55 | B | C |
| ATOM | 3036 | CG | MET | B | 478 | 34.403 | 47.381 | 52.148 | 1.00 | 20.87 | B | C |
| ATOM | 3037 | SD | MET | B | 478 | 32.713 | 47.872 | 51.737 | 1.00 | 25.11 | B | S |
| ATOM | 3038 | CE | MET | B | 478 | 32.911 | 49.644 | 51.547 | 1.00 | 22.83 | B | C |
| ATOM | 3039 | C | MET | B | 478 | 36.108 | 45.959 | 54.277 | 1.00 | 19.33 | B | C |
| ATOM | 3040 | O | MET | B | 478 | 36.713 | 47.001 | 54.534 | 1.00 | 18.83 | B | O |
| ATOM | 3041 | N | LEU | B | 479 | 35.560 | 45.177 | 55.203 | 1.00 | 19.00 | B | N |
| ATOM | 3042 | CA | LEU | B | 479 | 35.644 | 45.483 | 56.623 | 1.00 | 18.52 | B | C |
| ATOM | 3043 | CB | LEU | B | 479 | 34.816 | 44.478 | 57.427 | 1.00 | 16.99 | B | C |
| ATOM | 3044 | CG | LEU | B | 479 | 33.291 | 44.635 | 57.429 | 1.00 | 15.46 | B | C |
| ATOM | 3045 | CD1 | LEU | B | 479 | 32.665 | 43.429 | 58.124 | 1.00 | 12.54 | B | C |
| ATOM | 3046 | CD2 | LEU | B | 479 | 32.892 | 45.920 | 58.132 | 1.00 | 11.28 | B | C |
| ATOM | 3047 | C | LEU | B | 479 | 37.109 | 45.403 | 57.047 | 1.00 | 19.93 | B | C |
| ATOM | 3048 | O | LEU | B | 479 | 37.610 | 46.270 | 57.768 | 1.00 | 19.47 | B | O |
| ATOM | 3049 | N | GLU | B | 480 | 37.793 | 44.361 | 56.584 | 1.00 | 19.33 | B | N |
| ATOM | 3050 | CA | GLU | B | 480 | 39.200 | 44.172 | 56.911 | 1.00 | 19.91 | B | C |
| ATOM | 3051 | CB | GLU | B | 480 | 39.713 | 42.873 | 56.281 | 1.00 | 22.03 | B | C |
| ATOM | 3052 | CG | GLU | B | 480 | 41.233 | 42.730 | 56.272 | 1.00 | 27.40 | B | C |
| ATOM | 3053 | CD | GLU | B | 480 | 41.686 | 41.310 | 55.971 | 1.00 | 30.87 | B | C |
| ATOM | 3054 | OE1 | GLU | B | 480 | 40.872 | 40.521 | 55.447 | 1.00 | 32.97 | B | O |
| ATOM | 3055 | OE2 | GLU | B | 480 | 42.859 | 40.979 | 56.262 | 1.00 | 36.27 | B | O |
| ATOM | 3056 | C | GLU | B | 480 | 40.057 | 45.353 | 56.446 | 1.00 | 19.51 | B | C |
| ATOM | 3057 | O | GLU | B | 480 | 40.964 | 45.778 | 57.157 | 1.00 | 19.75 | B | O |
| ATOM | 3058 | N | ASN | B | 481 | 39.765 | 45.878 | 55.257 | 1.00 | 19.70 | B | N |
| ATOM | 3059 | CA | ASN | B | 481 | 40.516 | 47.007 | 54.707 | 1.00 | 19.84 | B | C |
| ATOM | 3060 | CB | ASN | B | 481 | 40.117 | 47.267 | 53.255 | 1.00 | 21.61 | B | C |
| ATOM | 3061 | CG | ASN | B | 481 | 40.639 | 46.215 | 52.307 | 1.00 | 24.54 | B | C |
| ATOM | 3062 | OD1 | ASN | B | 481 | 40.016 | 45.933 | 51.286 | 1.00 | 28.07 | B | O |
| ATOM | 3063 | ND2 | ASN | B | 481 | 41.789 | 45.627 | 52.635 | 1.00 | 26.79 | B | N |
| ATOM | 3064 | C | ASN | B | 481 | 40.262 | 48.272 | 55.504 | 1.00 | 17.87 | B | C |
| ATOM | 3065 | O | ASN | B | 481 | 41.150 | 49.112 | 55.658 | 1.00 | 17.33 | B | O |
| ATOM | 3066 | N | VAL | B | 482 | 39.038 | 48.413 | 55.997 | 1.00 | 15.92 | B | N |
| ATOM | 3067 | CA | VAL | B | 482 | 38.672 | 49.588 | 56.772 | 1.00 | 15.56 | B | C |
| ATOM | 3068 | CB | VAL | B | 482 | 37.124 | 49.724 | 56.904 | 1.00 | 15.63 | B | C |
| ATOM | 3069 | CG1 | VAL | B | 482 | 36.781 | 50.964 | 57.718 | 1.00 | 14.92 | B | C |
| ATOM | 3070 | CG2 | VAL | B | 482 | 36.478 | 49.815 | 55.536 | 1.00 | 13.00 | B | C |
| ATOM | 3071 | C | VAL | B | 482 | 39.276 | 49.561 | 58.181 | 1.00 | 17.10 | B | C |
| ATOM | 3072 | O | VAL | B | 482 | 39.829 | 50.559 | 58.651 | 1.00 | 16.50 | B | O |
| ATOM | 3073 | N | PHE | B | 483 | 39.203 | 48.412 | 58.845 | 1.00 | 16.73 | B | N |
| ATOM | 3074 | CA | PHE | B | 483 | 39.692 | 48.324 | 60.214 | 1.00 | 17.40 | B | C |
| ATOM | 3075 | CB | PHE | B | 483 | 38.630 | 47.638 | 61.066 | 1.00 | 14.55 | B | C |
| ATOM | 3076 | CG | PHE | B | 483 | 37.326 | 48.376 | 61.104 | 1.00 | 14.68 | B | C |
| ATOM | 3077 | CD1 | PHE | B | 483 | 37.216 | 49.580 | 61.782 | 1.00 | 15.51 | B | C |
| ATOM | 3078 | CD2 | PHE | B | 483 | 36.214 | 47.883 | 60.443 | 1.00 | 14.83 | B | C |
| ATOM | 3079 | CE1 | PHE | B | 483 | 36.017 | 50.280 | 61.798 | 1.00 | 14.40 | B | C |
| ATOM | 3080 | CE2 | PHE | B | 483 | 35.012 | 48.578 | 60.454 | 1.00 | 11.81 | B | C |
| ATOM | 3081 | CZ | PHE | B | 483 | 34.915 | 49.777 | 61.133 | 1.00 | 12.12 | B | C |
| ATOM | 3082 | C | PHE | B | 483 | 41.054 | 47.707 | 60.525 | 1.00 | 17.29 | B | C |
| ATOM | 3083 | O | PHE | B | 483 | 41.733 | 48.166 | 61.441 | 1.00 | 21.10 | B | O |
| ATOM | 3084 | N | MET | B | 484 | 41.464 | 46.679 | 59.795 | 1.00 | 17.97 | B | N |
| ATOM | 3085 | CA | MET | B | 484 | 42.744 | 46.037 | 60.080 | 1.00 | 20.15 | B | C |
| ATOM | 3086 | CB | MET | B | 484 | 43.034 | 44.952 | 59.039 | 1.00 | 20.95 | B | C |
| ATOM | 3087 | CG | MET | B | 484 | 44.189 | 44.027 | 59.400 | 1.00 | 24.57 | B | C |
| ATOM | 3088 | SD | MET | B | 484 | 43.915 | 43.011 | 60.885 | 1.00 | 25.49 | B | S |
| ATOM | 3089 | CE | MET | B | 484 | 42.968 | 41.664 | 60.226 | 1.00 | 23.71 | B | C |
| ATOM | 3090 | C | MET | B | 484 | 43.935 | 46.998 | 60.177 | 1.00 | 22.05 | B | C |
| ATOM | 3091 | O | MET | B | 484 | 44.695 | 46.964 | 61.149 | 1.00 | 25.50 | B | O |
| ATOM | 3092 | N | PRO | B | 485 | 44.119 | 47.868 | 59.175 | 1.00 | 21.49 | B | N |
| ATOM | 3093 | CD | PRO | B | 485 | 43.339 | 48.040 | 57.941 | 1.00 | 20.15 | B | C |
| ATOM | 3094 | CA | PRO | B | 485 | 45.251 | 48.797 | 59.239 | 1.00 | 21.62 | B | C |
| ATOM | 3095 | CB | PRO | B | 485 | 45.115 | 49.619 | 57.957 | 1.00 | 19.75 | B | C |
| ATOM | 3096 | CG | PRO | B | 485 | 44.291 | 48.775 | 57.048 | 1.00 | 19.94 | B | C |
| ATOM | 3097 | C | PRO | B | 485 | 45.285 | 49.680 | 60.485 | 1.00 | 23.29 | B | C |
| ATOM | 3098 | O | PRO | B | 485 | 46.364 | 50.055 | 60.957 | 1.00 | 26.13 | B | O |
| ATOM | 3099 | N | VAL | B | 486 | 44.114 | 50.024 | 61.009 | 1.00 | 22.46 | B | N |
| ATOM | 3100 | CA | VAL | B | 486 | 44.044 | 50.874 | 62.192 | 1.00 | 23.56 | B | C |
| ATOM | 3101 | CB | VAL | B | 486 | 42.650 | 51.491 | 62.361 | 1.00 | 23.61 | B | C |
| ATOM | 3102 | CG1 | VAL | B | 486 | 42.759 | 52.773 | 63.148 | 1.00 | 26.26 | B | C |
| ATOM | 3103 | CG2 | VAL | B | 486 | 42.039 | 51.767 | 61.004 | 1.00 | 23.70 | B | C |
| ATOM | 3104 | C | VAL | B | 486 | 44.397 | 50.096 | 63.455 | 1.00 | 23.48 | B | C |
| ATOM | 3105 | O | VAL | B | 486 | 45.020 | 50.637 | 64.373 | 1.00 | 23.97 | B | O |
| ATOM | 3106 | N | PHE | B | 487 | 43.990 | 48.830 | 63.500 | 1.00 | 21.48 | B | N |
| ATOM | 3107 | CA | PHE | B | 487 | 44.295 | 47.972 | 64.637 | 1.00 | 22.88 | B | C |
| ATOM | 3108 | CB | PHE | B | 487 | 43.610 | 46.615 | 64.479 | 1.00 | 21.01 | B | C |
| ATOM | 3109 | CG | PHE | B | 487 | 42.224 | 46.558 | 65.061 | 1.00 | 22.52 | B | C |
| ATOM | 3110 | CD1 | PHE | B | 487 | 41.124 | 46.955 | 64.307 | 1.00 | 23.83 | B | C |
| ATOM | 3111 | CD2 | PHE | B | 487 | 42.016 | 46.115 | 66.362 | 1.00 | 19.87 | B | C |
| ATOM | 3112 | CE1 | PHE | B | 487 | 39.833 | 46.913 | 64.841 | 1.00 | 21.14 | B | C |
| ATOM | 3113 | CE2 | PHE | B | 487 | 40.736 | 46.068 | 66.905 | 1.00 | 18.54 | B | C |
| ATOM | 3114 | CZ | PHE | B | 487 | 39.642 | 46.467 | 66.145 | 1.00 | 21.88 | B | C |
| ATOM | 3115 | C | PHE | B | 487 | 45.810 | 47.776 | 64.666 | 1.00 | 25.46 | B | C |
| ATOM | 3116 | O | PHE | B | 487 | 46.450 | 47.893 | 65.713 | 1.00 | 26.42 | B | O |
| ATOM | 3117 | N | GLU | B | 488 | 46.377 | 47.492 | 63.498 | 1.00 | 26.21 | B | N |
| ATOM | 3118 | CA | GLU | B | 488 | 47.812 | 47.279 | 63.361 | 1.00 | 28.07 | B | C |
| ATOM | 3119 | CB | GLU | B | 488 | 48.168 | 47.010 | 61.895 | 1.00 | 31.11 | B | C |
| ATOM | 3120 | CG | GLU | B | 488 | 48.461 | 45.552 | 61.578 | 1.00 | 36.38 | B | C |
| ATOM | 3121 | CD | GLU | B | 488 | 48.044 | 45.161 | 60.162 | 1.00 | 40.60 | B | C |
| ATOM | 3122 | OE1 | GLU | B | 488 | 47.892 | 46.070 | 59.312 | 1.00 | 40.51 | B | O |
| ATOM | 3123 | OE2 | GLU | B | 488 | 47.871 | 43.945 | 59.900 | 1.00 | 40.12 | B | O |
| ATOM | 3124 | C | GLU | B | 488 | 48.631 | 48.459 | 63.873 | 1.00 | 24.85 | B | C |
| ATOM | 3125 | O | GLU | B | 488 | 49.653 | 48.268 | 64.522 | 1.00 | 25.29 | B | O |
| ATOM | 3126 | N | ALA | B | 489 | 48.191 | 49.674 | 63.574 | 1.00 | 22.51 | B | N |
| ATOM | 3127 | CA | ALA | B | 489 | 48.908 | 50.864 | 64.030 | 1.00 | 23.94 | B | C |
| ATOM | 3128 | CB | ALA | B | 489 | 48.450 | 52.082 | 63.235 | 1.00 | 20.65 | B | C |
| ATOM | 3129 | C | ALA | B | 489 | 48.696 | 51.104 | 65.530 | 1.00 | 22.37 | B | C |
| ATOM | 3130 | O | ALA | B | 489 | 49.447 | 51.849 | 66.162 | 1.00 | 21.12 | B | O |
| ATOM | 3131 | N | THR | B | 490 | 47.666 | 50.470 | 66.085 | 1.00 | 22.78 | B | N |
| ATOM | 3132 | CA | THR | B | 490 | 47.341 | 50.598 | 67.504 | 1.00 | 24.40 | B | C |
| ATOM | 3133 | CB | THR | B | 490 | 45.865 | 50.200 | 67.775 | 1.00 | 23.31 | B | C |
| ATOM | 3134 | OG1 | THR | B | 490 | 44.991 | 51.208 | 67.253 | 1.00 | 21.42 | B | O |
| ATOM | 3135 | CG2 | THR | B | 490 | 45.613 | 50.051 | 69.265 | 1.00 | 23.91 | B | C |
| ATOM | 3136 | C | THR | B | 490 | 48.254 | 49.679 | 68.312 | 1.00 | 27.04 | B | C |
| ATOM | 3137 | O | THR | B | 490 | 48.811 | 50.062 | 69.338 | 1.00 | 28.79 | B | O |
| ATOM | 3138 | N | ILE | B | 491 | 48.404 | 48.459 | 67.822 | 1.00 | 27.78 | B | N |
| ATOM | 3139 | CA | ILE | B | 491 | 49.235 | 47.459 | 68.461 | 1.00 | 27.11 | B | C |
| ATOM | 3140 | CB | ILE | B | 491 | 48.891 | 46.073 | 67.882 | 1.00 | 26.78 | B | C |
| ATOM | 3141 | CG2 | ILE | B | 491 | 50.134 | 45.335 | 67.447 | 1.00 | 31.76 | B | C |
| ATOM | 3142 | CG1 | ILE | B | 491 | 48.110 | 45.282 | 68.914 | 1.00 | 26.16 | B | C |
| ATOM | 3143 | CD1 | ILE | B | 491 | 46.671 | 45.121 | 68.543 | 1.00 | 29.57 | B | C |
| ATOM | 3144 | C | ILE | B | 491 | 50.729 | 47.764 | 68.290 | 1.00 | 28.70 | B | C |
| ATOM | 3145 | O | ILE | B | 491 | 51.502 | 47.637 | 69.238 | 1.00 | 31.53 | B | O |
| ATOM | 3146 | N | ASN | B | 492 | 51.132 | 48.173 | 67.087 | 1.00 | 27.75 | B | N |
| ATOM | 3147 | CA | ASN | B | 492 | 52.533 | 48.485 | 66.806 | 1.00 | 26.08 | B | C |
| ATOM | 3148 | CB | ASN | B | 492 | 53.091 | 47.488 | 65.788 | 1.00 | 26.55 | B | C |
| ATOM | 3149 | CG | ASN | B | 492 | 52.965 | 46.045 | 66.258 | 1.00 | 27.11 | B | C |
| ATOM | 3150 | OD1 | ASN | B | 492 | 53.407 | 45.700 | 67.355 | 1.00 | 30.81 | B | O |
| ATOM | 3151 | ND2 | ASN | B | 492 | 52.362 | 45.196 | 65.430 | 1.00 | 21.55 | B | N |
| ATOM | 3152 | C | ASN | B | 492 | 52.695 | 49.909 | 66.279 | 1.00 | 24.43 | B | C |
| ATOM | 3153 | O | ASN | B | 492 | 53.019 | 50.120 | 65.116 | 1.00 | 25.03 | B | O |
| ATOM | 3154 | N | PRO | B | 493 | 52.493 | 50.908 | 67.148 | 1.00 | 24.17 | B | N |
| ATOM | 3155 | CD | PRO | B | 493 | 52.137 | 50.759 | 68.568 | 1.00 | 21.84 | B | C |
| ATOM | 3156 | CA | PRO | B | 493 | 52.612 | 52.317 | 66.758 | 1.00 | 24.16 | B | C |
| ATOM | 3157 | CB | PRO | B | 493 | 52.245 | 53.081 | 68.033 | 1.00 | 22.02 | B | C |
| ATOM | 3158 | CG | PRO | B | 493 | 51.542 | 52.085 | 68.900 | 1.00 | 21.44 | B | C |
| ATOM | 3159 | C | PRO | B | 493 | 53.970 | 52.745 | 66.213 | 1.00 | 26.00 | B | C |
| ATOM | 3160 | O | PRO | B | 493 | 54.066 | 53.726 | 65.480 | 1.00 | 28.30 | B | O |
| ATOM | 3161 | N | GLN | B | 494 | 55.024 | 52.030 | 66.573 | 1.00 | 29.64 | B | N |
| ATOM | 3162 | CA | GLN | B | 494 | 56.352 | 52.389 | 66.092 | 1.00 | 32.86 | B | C |
| ATOM | 3163 | CB | GLN | B | 494 | 57.416 | 51.780 | 66.996 | 1.00 | 36.62 | B | C |
| ATOM | 3164 | CG | GLN | B | 494 | 57.242 | 52.153 | 68.455 | 1.00 | 41.17 | B | C |
| ATOM | 3165 | CD | GLN | B | 494 | 57.806 | 53.516 | 68.779 | 1.00 | 41.49 | B | C |
| ATOM | 3166 | OE1 | GLN | B | 494 | 58.241 | 53.761 | 69.902 | 1.00 | 46.95 | B | O |
| ATOM | 3167 | NE2 | GLN | B | 494 | 57.804 | 54.412 | 67.799 | 1.00 | 43.58 | B | N |
| ATOM | 3168 | C | GLN | B | 494 | 56.560 | 51.924 | 64.656 | 1.00 | 32.86 | B | C |
| ATOM | 3169 | O | GLN | B | 494 | 57.332 | 52.519 | 63.906 | 1.00 | 33.31 | B | O |
| ATOM | 3170 | N | ALA | B | 495 | 55.866 | 50.856 | 64.281 | 1.00 | 31.88 | B | N |
| ATOM | 3171 | CA | ALA | B | 495 | 55.960 | 50.316 | 62.935 | 1.00 | 31.29 | B | C |
| ATOM | 3172 | CB | ALA | B | 495 | 55.409 | 48.907 | 62.906 | 1.00 | 30.07 | B | C |
| ATOM | 3173 | C | ALA | B | 495 | 55.178 | 51.205 | 61.975 | 1.00 | 33.22 | B | C |
| ATOM | 3174 | O | ALA | B | 495 | 55.527 | 51.322 | 60.796 | 1.00 | 36.48 | B | O |
| ATOM | 3175 | N | HIS | B | 496 | 54.123 | 51.835 | 62.489 | 1.00 | 30.36 | B | N |
| ATOM | 3176 | CA | HIS | B | 496 | 53.278 | 52.716 | 61.687 | 1.00 | 28.15 | B | C |
| ATOM | 3177 | CB | HIS | B | 496 | 51.894 | 52.094 | 61.544 | 1.00 | 25.72 | B | C |
| ATOM | 3178 | CG | HIS | B | 496 | 51.927 | 50.645 | 61.167 | 1.00 | 28.00 | B | C |
| ATOM | 3179 | CD2 | HIS | B | 496 | 51.535 | 49.538 | 61.841 | 1.00 | 29.53 | B | C |
| ATOM | 3180 | ND1 | HIS | B | 496 | 52.422 | 50.202 | 59.960 | 1.00 | 30.60 | B | N |
| ATOM | 3181 | CE1 | HIS | B | 496 | 52.334 | 48.885 | 59.906 | 1.00 | 25.96 | B | C |
| ATOM | 3182 | NE2 | HIS | B | 496 | 51.799 | 48.456 | 61.035 | 1.00 | 26.18 | B | N |
| ATOM | 3183 | C | HIS | B | 496 | 53.173 | 54.099 | 62.333 | 1.00 | 26.42 | B | C |
| ATOM | 3184 | O | HIS | B | 496 | 52.104 | 54.514 | 62.773 | 1.00 | 26.30 | B | O |
| ATOM | 3185 | N | PRO | B | 497 | 54.293 | 54.831 | 62.398 | 1.00 | 25.05 | B | N |
| ATOM | 3186 | CD | PRO | B | 497 | 55.615 | 54.404 | 61.913 | 1.00 | 22.66 | B | C |
| ATOM | 3187 | CA | PRO | B | 497 | 54.338 | 56.171 | 62.993 | 1.00 | 24.89 | B | C |
| ATOM | 3188 | CB | PRO | B | 497 | 55.807 | 56.570 | 62.876 | 1.00 | 24.49 | B | C |
| ATOM | 3189 | CG | PRO | B | 497 | 56.359 | 55.698 | 61.802 | 1.00 | 22.37 | B | C |
| ATOM | 3190 | C | PRO | B | 497 | 53.421 | 57.230 | 62.386 | 1.00 | 26.25 | B | C |
| ATOM | 3191 | O | PRO | B | 497 | 52.715 | 57.926 | 63.114 | 1.00 | 28.34 | B | O |
| ATOM | 3192 | N | GLU | B | 498 | 53.443 | 57.368 | 61.063 | 1.00 | 26.09 | B | N |
| ATOM | 3193 | CA | GLU | B | 498 | 52.624 | 58.372 | 60.389 | 1.00 | 25.51 | B | C |
| ATOM | 3194 | CB | GLU | B | 498 | 52.966 | 58.428 | 58.897 | 1.00 | 28.08 | B | C |
| ATOM | 3195 | CG | GLU | B | 498 | 53.374 | 59.818 | 58.426 | 1.00 | 32.43 | B | C |
| ATOM | 3196 | CD | GLU | B | 498 | 53.782 | 59.861 | 56.961 | 1.00 | 36.99 | B | C |
| ATOM | 3197 | OE1 | GLU | B | 498 | 53.444 | 58.921 | 56.210 | 1.00 | 39.79 | B | O |
| ATOM | 3198 | OE2 | GLU | B | 498 | 54.444 | 60.845 | 56.557 | 1.00 | 40.75 | B | O |
| ATOM | 3199 | C | GLU | B | 498 | 51.134 | 58.118 | 60.574 | 1.00 | 24.70 | B | C |
| ATOM | 3200 | O | GLU | B | 498 | 50.357 | 59.043 | 60.831 | 1.00 | 23.48 | B | O |
| ATOM | 3201 | N | LEU | B | 499 | 50.731 | 56.862 | 60.444 | 1.00 | 21.04 | B | N |
| ATOM | 3202 | CA | LEU | B | 499 | 49.333 | 56.515 | 60.619 | 1.00 | 20.64 | B | C |
| ATOM | 3203 | CB | LEU | B | 499 | 49.102 | 55.056 | 60.230 | 1.00 | 18.16 | B | C |
| ATOM | 3204 | CG | LEU | B | 499 | 47.703 | 54.484 | 60.481 | 1.00 | 18.97 | B | C |
| ATOM | 3205 | CD1 | LEU | B | 499 | 46.646 | 55.427 | 59.926 | 1.00 | 11.75 | B | C |
| ATOM | 3206 | CD2 | LEU | B | 499 | 47.594 | 53.106 | 59.832 | 1.00 | 15.04 | B | C |
| ATOM | 3207 | C | LEU | B | 499 | 48.945 | 56.736 | 62.084 | 1.00 | 21.79 | B | C |
| ATOM | 3208 | O | LEU | B | 499 | 47.860 | 57.227 | 62.379 | 1.00 | 22.75 | B | O |
| ATOM | 3209 | N | SER | B | 500 | 49.846 | 56.376 | 62.995 | 1.00 | 22.88 | B | N |
| ATOM | 3210 | CA | SER | B | 500 | 49.604 | 56.530 | 64.426 | 1.00 | 22.47 | B | C |
| ATOM | 3211 | CB | SER | B | 500 | 50.822 | 56.049 | 65.225 | 1.00 | 22.43 | B | C |
| ATOM | 3212 | OG | SER | B | 500 | 50.900 | 54.632 | 65.254 | 1.00 | 19.54 | B | O |
| ATOM | 3213 | C | SER | B | 500 | 49.317 | 57.988 | 64.767 | 1.00 | 24.66 | B | C |
| ATOM | 3214 | O | SER | B | 500 | 48.400 | 58.290 | 65.535 | 1.00 | 26.97 | B | O |
| ATOM | 3215 | N | VAL | B | 501 | 50.110 | 58.889 | 64.197 | 1.00 | 22.69 | B | N |
| ATOM | 3216 | CA | VAL | B | 501 | 49.947 | 60.313 | 64.438 | 1.00 | 22.48 | B | C |
| ATOM | 3217 | CB | VAL | B | 501 | 51.100 | 61.103 | 63.796 | 1.00 | 22.03 | B | C |
| ATOM | 3218 | CG1 | VAL | B | 501 | 50.722 | 62.565 | 63.630 | 1.00 | 21.76 | B | C |
| ATOM | 3219 | CG2 | VAL | B | 501 | 52.337 | 60.975 | 64.657 | 1.00 | 20.84 | B | C |
| ATOM | 3220 | C | VAL | B | 501 | 48.617 | 60.789 | 63.861 | 1.00 | 25.83 | B | C |
| ATOM | 3221 | O | VAL | B | 501 | 47.877 | 61.544 | 64.499 | 1.00 | 26.23 | B | O |
| ATOM | 3222 | N | PHE | B | 502 | 48.315 | 60.334 | 62.651 | 1.00 | 25.13 | B | N |
| ATOM | 3223 | CA | PHE | B | 502 | 47.080 | 60.704 | 61.975 | 1.00 | 21.17 | B | C |
| ATOM | 3224 | CB | PHE | B | 502 | 47.014 | 59.986 | 60.618 | 1.00 | 21.93 | B | C |
| ATOM | 3225 | CG | PHE | B | 502 | 45.765 | 60.275 | 59.822 | 1.00 | 19.32 | B | C |
| ATOM | 3226 | CD1 | PHE | B | 502 | 45.380 | 61.582 | 59.546 | 1.00 | 16.72 | B | C |
| ATOM | 3227 | CD2 | PHE | B | 502 | 44.981 | 59.232 | 59.340 | 1.00 | 17.48 | B | C |
| ATOM | 3228 | CE1 | PHE | B | 502 | 44.227 | 61.843 | 58.801 | 1.00 | 19.06 | B | C |
| ATOM | 3229 | CE2 | PHE | B | 502 | 43.830 | 59.483 | 58.595 | 1.00 | 17.80 | B | C |
| ATOM | 3230 | CZ | PHE | B | 502 | 43.453 | 60.790 | 58.325 | 1.00 | 15.79 | B | C |
| ATOM | 3231 | C | PHE | B | 502 | 45.884 | 60.326 | 62.848 | 1.00 | 21.61 | B | C |
| ATOM | 3232 | O | PHE | B | 502 | 44.986 | 61.139 | 63.077 | 1.00 | 20.36 | B | O |
| ATOM | 3233 | N | LEU | B | 503 | 45.887 | 59.092 | 63.345 | 1.00 | 21.66 | B | N |
| ATOM | 3234 | CA | LEU | B | 503 | 44.810 | 58.583 | 64.190 | 1.00 | 20.95 | B | C |
| ATOM | 3235 | CB | LEU | B | 503 | 45.126 | 57.157 | 64.632 | 1.00 | 15.59 | B | C |
| ATOM | 3236 | CG | LEU | B | 503 | 45.009 | 56.121 | 63.517 | 1.00 | 17.81 | B | C |
| ATOM | 3237 | CD1 | LEU | B | 503 | 45.435 | 54.762 | 64.032 | 1.00 | 14.21 | B | C |
| ATOM | 3238 | CD2 | LEU | B | 503 | 43.573 | 56.081 | 63.003 | 1.00 | 16.08 | B | C |
| ATOM | 3239 | C | LEU | B | 503 | 44.524 | 59.446 | 65.420 | 1.00 | 21.01 | B | C |
| ATOM | 3240 | O | LEU | B | 503 | 43.441 | 59.373 | 65.991 | 1.00 | 24.20 | B | O |
| ATOM | 3241 | N | LYS | B | 504 | 45.491 | 60.253 | 65.836 | 1.00 | 21.12 | B | N |
| ATOM | 3242 | CA | LYS | B | 504 | 45.287 | 61.122 | 66.989 | 1.00 | 22.18 | B | C |
| ATOM | 3243 | CB | LYS | B | 504 | 46.623 | 61.622 | 67.530 | 1.00 | 19.47 | B | C |
| ATOM | 3244 | CG | LYS | B | 504 | 47.339 | 60.604 | 68.376 | 1.00 | 23.41 | B | C |
| ATOM | 3245 | CD | LYS | B | 504 | 48.772 | 61.020 | 68.630 | 1.00 | 28.04 | B | C |
| ATOM | 3246 | CE | LYS | B | 504 | 48.850 | 62.129 | 69.657 | 1.00 | 31.48 | B | C |
| ATOM | 3247 | NZ | LYS | B | 504 | 50.219 | 62.719 | 69.685 | 1.00 | 39.49 | B | N |
| ATOM | 3248 | C | LYS | B | 504 | 44.441 | 62.315 | 66.577 | 1.00 | 21.84 | B | C |
| ATOM | 3249 | O | LYS | B | 504 | 43.947 | 63.049 | 67.427 | 1.00 | 22.48 | B | O |
| ATOM | 3250 | N | HIS | B | 505 | 44.278 | 62.493 | 65.266 | 1.00 | 21.16 | B | N |
| ATOM | 3251 | CA | HIS | B | 505 | 43.516 | 63.606 | 64.711 | 1.00 | 16.83 | B | C |
| ATOM | 3252 | CB | HIS | B | 505 | 44.278 | 64.216 | 63.538 | 1.00 | 17.36 | B | C |
| ATOM | 3253 | CG | HIS | B | 505 | 45.526 | 64.938 | 63.940 | 1.00 | 20.27 | B | C |
| ATOM | 3254 | CD2 | HIS | B | 505 | 46.752 | 64.478 | 64.279 | 1.00 | 20.63 | B | C |
| ATOM | 3255 | ND1 | HIS | B | 505 | 45.593 | 66.312 | 64.037 | 1.00 | 24.75 | B | N |
| ATOM | 3256 | CE1 | HIS | B | 505 | 46.809 | 66.665 | 64.417 | 1.00 | 22.28 | B | C |
| ATOM | 3257 | NE2 | HIS | B | 505 | 47.532 | 65.572 | 64.570 | 1.00 | 19.00 | B | N |
| ATOM | 3258 | C | HIS | B | 505 | 42.114 | 63.237 | 64.260 | 1.00 | 14.76 | B | C |
| ATOM | 3259 | O | HIS | B | 505 | 41.333 | 64.114 | 63.913 | 1.00 | 16.79 | B | O |
| ATOM | 3260 | N | ILE | B | 506 | 41.804 | 61.943 | 64.263 | 1.00 | 14.06 | B | N |
| ATOM | 3261 | CA | ILE | B | 506 | 40.489 | 61.454 | 63.857 | 1.00 | 14.09 | B | C |
| ATOM | 3262 | CB | ILE | B | 506 | 40.590 | 60.071 | 63.158 | 1.00 | 12.02 | B | C |
| ATOM | 3263 | CG2 | ILE | B | 506 | 39.203 | 59.514 | 62.883 | 1.00 | 8.63 | B | C |
| ATOM | 3264 | CG1 | ILE | B | 506 | 41.386 | 60.199 | 61.851 | 1.00 | 12.56 | B | C |
| ATOM | 3265 | CD1 | ILE | B | 506 | 40.919 | 61.309 | 60.920 | 1.00 | 13.46 | B | C |
| ATOM | 3266 | C | ILE | B | 506 | 39.626 | 61.320 | 65.104 | 1.00 | 17.05 | B | C |
| ATOM | 3267 | O | ILE | B | 506 | 39.992 | 60.609 | 66.044 | 1.00 | 21.03 | B | O |
| ATOM | 3268 | N | THR | B | 507 | 38.481 | 62.002 | 65.105 | 1.00 | 17.11 | B | N |
| ATOM | 3269 | CA | THR | B | 507 | 37.566 | 61.987 | 66.243 | 1.00 | 15.88 | B | C |
| ATOM | 3270 | CB | THR | B | 507 | 36.929 | 63.394 | 66.458 | 1.00 | 14.08 | B | C |
| ATOM | 3271 | OG1 | THR | B | 507 | 35.997 | 63.678 | 65.410 | 1.00 | 19.86 | B | O |
| ATOM | 3272 | CG2 | THR | B | 507 | 37.994 | 64.463 | 66.450 | 1.00 | 9.02 | B | C |
| ATOM | 3273 | C | THR | B | 507 | 36.459 | 60.929 | 66.133 | 1.00 | 15.00 | B | C |
| ATOM | 3274 | O | THR | B | 507 | 35.956 | 60.439 | 67.153 | 1.00 | 14.56 | B | O |
| ATOM | 3275 | N | GLY | B | 508 | 36.088 | 60.561 | 64.909 | 1.00 | 12.72 | B | N |
| ATOM | 3276 | CA | GLY | B | 508 | 35.047 | 59.559 | 64.749 | 1.00 | 10.51 | B | C |
| ATOM | 3277 | C | GLY | B | 508 | 34.847 | 59.021 | 63.346 | 1.00 | 11.47 | B | C |
| ATOM | 3278 | O | GLY | B | 508 | 35.501 | 59.458 | 62.394 | 1.00 | 9.10 | B | O |
| ATOM | 3279 | N | PHE | B | 509 | 33.926 | 58.065 | 63.226 | 1.00 | 11.97 | B | N |
| ATOM | 3280 | CA | PHE | B | 509 | 33.604 | 57.433 | 61.954 | 1.00 | 13.06 | B | C |
| ATOM | 3281 | CB | PHE | B | 509 | 33.745 | 55.923 | 62.072 | 1.00 | 11.75 | B | C |
| ATOM | 3282 | CG | PHE | B | 509 | 35.161 | 55.459 | 62.119 | 1.00 | 18.51 | B | C |
| ATOM | 3283 | CD1 | PHE | B | 509 | 35.819 | 55.065 | 60.952 | 1.00 | 17.96 | B | C |
| ATOM | 3284 | CD2 | PHE | B | 509 | 35.856 | 55.431 | 63.327 | 1.00 | 18.53 | B | C |
| ATOM | 3285 | CE1 | PHE | B | 509 | 37.152 | 54.652 | 60.985 | 1.00 | 19.66 | B | C |
| ATOM | 3286 | CE2 | PHE | B | 509 | 37.194 | 55.018 | 63.373 | 1.00 | 18.62 | B | C |
| ATOM | 3287 | CZ | PHE | B | 509 | 37.842 | 54.629 | 62.200 | 1.00 | 19.57 | B | C |
| ATOM | 3288 | C | PHE | B | 509 | 32.196 | 57.764 | 61.475 | 1.00 | 15.49 | B | C |
| ATOM | 3289 | O | PHE | B | 509 | 31.273 | 57.889 | 62.280 | 1.00 | 15.38 | B | O |
| ATOM | 3290 | N | ASP | B | 510 | 32.045 | 57.896 | 60.157 | 1.00 | 15.82 | B | N |
| ATOM | 3291 | CA | ASP | B | 510 | 30.760 | 58.208 | 59.534 | 1.00 | 16.15 | B | C |
| ATOM | 3292 | CB | ASP | B | 510 | 30.809 | 59.608 | 58.916 | 1.00 | 16.98 | B | C |
| ATOM | 3293 | CG | ASP | B | 510 | 29.429 | 60.193 | 58.676 | 1.00 | 17.70 | B | C |
| ATOM | 3294 | OD1 | ASP | B | 510 | 28.444 | 59.423 | 58.663 | 1.00 | 20.42 | B | O |
| ATOM | 3295 | OD2 | ASP | B | 510 | 29.326 | 61.425 | 58.496 | 1.00 | 19.18 | B | O |
| ATOM | 3296 | C | ASP | B | 510 | 30.458 | 57.173 | 58.452 | 1.00 | 17.18 | B | C |
| ATOM | 3297 | O | ASP | B | 510 | 31.367 | 56.521 | 57.945 | 1.00 | 19.29 | B | O |
| ATOM | 3298 | N | SER | B | 511 | 29.181 | 57.013 | 58.112 | 1.00 | 18.35 | B | N |
| ATOM | 3299 | CA | SER | B | 511 | 28.753 | 56.063 | 57.085 | 1.00 | 17.81 | B | C |
| ATOM | 3300 | CB | SER | B | 511 | 27.995 | 54.910 | 57.735 | 1.00 | 14.87 | B | C |
| ATOM | 3301 | OG | SER | B | 511 | 27.044 | 54.346 | 56.858 | 1.00 | 15.96 | B | O |
| ATOM | 3302 | C | SER | B | 511 | 27.852 | 56.834 | 56.113 | 1.00 | 21.24 | B | C |
| ATOM | 3303 | O | SER | B | 511 | 26.774 | 57.278 | 56.480 | 1.00 | 22.02 | B | O |
| ATOM | 3304 | N | VAL | B | 512 | 28.307 | 56.986 | 54.872 | 1.00 | 24.65 | B | N |
| ATOM | 3305 | CA | VAL | B | 512 | 27.584 | 57.751 | 53.857 | 1.00 | 22.65 | B | C |
| ATOM | 3306 | CB | VAL | B | 512 | 28.456 | 58.925 | 53.399 | 1.00 | 19.92 | B | C |
| ATOM | 3307 | CG1 | VAL | B | 512 | 28.977 | 59.685 | 54.607 | 1.00 | 17.18 | B | C |
| ATOM | 3308 | CG2 | VAL | B | 512 | 29.642 | 58.402 | 52.609 | 1.00 | 18.88 | B | C |
| ATOM | 3309 | C | VAL | B | 512 | 27.171 | 56.930 | 52.628 | 1.00 | 25.52 | B | C |
| ATOM | 3310 | O | VAL | B | 512 | 27.617 | 55.799 | 52.455 | 1.00 | 26.08 | B | O |
| ATOM | 3311 | N | ASP | B | 513 | 26.339 | 57.523 | 51.772 | 1.00 | 29.93 | B | N |
| ATOM | 3312 | CA | ASP | B | 513 | 25.829 | 56.872 | 50.554 | 1.00 | 33.72 | B | C |
| ATOM | 3313 | CB | ASP | B | 513 | 25.938 | 55.322 | 50.638 | 1.00 | 40.66 | B | C |
| ATOM | 3314 | CG | ASP | B | 513 | 25.261 | 54.578 | 49.435 | 1.00 | 43.71 | B | C |
| ATOM | 3315 | OD1 | ASP | B | 513 | 25.413 | 55.028 | 48.270 | 1.00 | 46.05 | B | O |
| ATOM | 3316 | OD2 | ASP | B | 513 | 24.589 | 53.535 | 49.657 | 1.00 | 37.64 | B | O |
| ATOM | 3317 | C | ASP | B | 513 | 24.362 | 57.236 | 50.438 | 1.00 | 31.23 | B | C |
| ATOM | 3318 | O | ASP | B | 513 | 23.804 | 57.905 | 51.307 | 1.00 | 31.62 | B | O |
| ATOM | 3319 | N | ASP | B | 514 | 23.744 | 56.798 | 49.352 | 1.00 | 29.20 | B | N |
| ATOM | 3320 | CA | ASP | B | 514 | 22.332 | 57.031 | 49.154 | 1.00 | 30.23 | B | C |
| ATOM | 3321 | CB | ASP | B | 514 | 21.911 | 56.485 | 47.794 | 1.00 | 28.49 | B | C |
| ATOM | 3322 | CG | ASP | B | 514 | 20.510 | 56.883 | 47.419 | 1.00 | 31.25 | B | C |
| ATOM | 3323 | OD1 | ASP | B | 514 | 19.736 | 57.289 | 48.311 | 1.00 | 30.19 | B | O |
| ATOM | 3324 | OD2 | ASP | B | 514 | 20.182 | 56.787 | 46.222 | 1.00 | 36.93 | B | O |
| ATOM | 3325 | C | ASP | B | 514 | 21.681 | 56.222 | 50.272 | 1.00 | 29.93 | B | C |
| ATOM | 3326 | O | ASP | B | 514 | 22.125 | 55.114 | 50.561 | 1.00 | 30.45 | B | O |
| ATOM | 3327 | N | GLU | B | 515 | 20.654 | 56.773 | 50.914 | 1.00 | 28.51 | B | N |
| ATOM | 3328 | CA | GLU | B | 515 | 19.975 | 56.059 | 51.988 | 1.00 | 25.93 | B | C |
| ATOM | 3329 | CB | GLU | B | 515 | 19.812 | 56.959 | 53.221 | 1.00 | 23.44 | B | C |
| ATOM | 3330 | CG | GLU | B | 515 | 20.031 | 56.241 | 54.550 | 1.00 | 19.34 | B | C |
| ATOM | 3331 | CD | GLU | B | 515 | 19.510 | 57.023 | 55.752 | 1.00 | 17.22 | B | C |
| ATOM | 3332 | OE1 | GLU | B | 515 | 19.645 | 58.265 | 55.771 | 1.00 | 17.75 | B | O |
| ATOM | 3333 | OE2 | GLU | B | 515 | 18.969 | 56.393 | 56.685 | 1.00 | 15.31 | B | O |
| ATOM | 3334 | C | GLU | B | 515 | 18.610 | 55.603 | 51.507 | 1.00 | 27.43 | B | C |
| ATOM | 3335 | O | GLU | B | 515 | 17.982 | 54.742 | 52.130 | 1.00 | 27.32 | B | O |
| ATOM | 3336 | N | SER | B | 516 | 18.157 | 56.178 | 50.392 | 1.00 | 30.49 | B | N |
| ATOM | 3337 | CA | SER | B | 516 | 16.845 | 55.845 | 49.824 | 1.00 | 34.03 | B | C |
| ATOM | 3338 | CB | SER | B | 516 | 16.362 | 56.964 | 48.893 | 1.00 | 34.65 | B | C |
| ATOM | 3339 | OG | SER | B | 516 | 17.285 | 57.194 | 47.836 | 1.00 | 33.70 | B | O |
| ATOM | 3340 | C | SER | B | 516 | 16.823 | 54.528 | 49.062 | 1.00 | 35.98 | B | C |
| ATOM | 3341 | O | SER | B | 516 | 15.759 | 53.952 | 48.837 | 1.00 | 36.10 | B | O |
| ATOM | 3342 | N | LYS | B | 517 | 17.997 | 54.053 | 48.663 | 1.00 | 39.57 | B | N |
| ATOM | 3343 | CA | LYS | B | 517 | 18.091 | 52.803 | 47.927 | 1.00 | 43.57 | B | C |
| ATOM | 3344 | CB | LYS | B | 517 | 19.548 | 52.437 | 47.673 | 1.00 | 43.77 | B | C |
| ATOM | 3345 | CG | LYS | B | 517 | 19.998 | 52.646 | 46.237 | 1.00 | 42.63 | B | C |
| ATOM | 3346 | CD | LYS | B | 517 | 21.485 | 53.030 | 46.155 | 1.00 | 45.68 | B | C |
| ATOM | 3347 | CE | LYS | B | 517 | 22.314 | 52.493 | 47.337 | 1.00 | 44.39 | B | C |
| ATOM | 3348 | NZ | LYS | B | 517 | 22.895 | 51.151 | 47.061 | 1.00 | 43.05 | B | N |
| ATOM | 3349 | C | LYS | B | 517 | 17.417 | 51.662 | 48.666 | 1.00 | 48.44 | B | C |
| ATOM | 3350 | O | LYS | B | 517 | 17.406 | 51.610 | 49.898 | 1.00 | 50.03 | B | O |
| ATOM | 3351 | N | HIS | B | 518 | 16.855 | 50.755 | 47.879 | 1.00 | 53.83 | B | N |
| ATOM | 3352 | CA | HIS | B | 518 | 16.152 | 49.565 | 48.347 | 1.00 | 58.18 | B | C |
| ATOM | 3353 | CB | HIS | B | 518 | 15.483 | 48.897 | 47.153 | 1.00 | 62.86 | B | C |
| ATOM | 3354 | CG | HIS | B | 518 | 16.436 | 48.637 | 46.025 | 1.00 | 68.78 | B | C |
| ATOM | 3355 | CD2 | HIS | B | 518 | 16.827 | 49.420 | 44.988 | 1.00 | 70.04 | B | C |
| ATOM | 3356 | ND1 | HIS | B | 518 | 17.182 | 47.479 | 45.931 | 1.00 | 70.08 | B | N |
| ATOM | 3357 | CE1 | HIS | B | 518 | 17.990 | 47.560 | 44.889 | 1.00 | 70.98 | B | C |
| ATOM | 3358 | NE2 | HIS | B | 518 | 17.795 | 48.727 | 44.299 | 1.00 | 72.60 | B | N |
| ATOM | 3359 | C | HIS | B | 518 | 17.146 | 48.570 | 48.938 | 1.00 | 59.50 | B | C |
| ATOM | 3360 | O | HIS | B | 518 | 18.337 | 48.601 | 48.616 | 1.00 | 61.11 | B | O |
| ATOM | 3361 | N | SER | B | 519 | 16.651 | 47.674 | 49.784 | 1.00 | 57.88 | B | N |
| ATOM | 3362 | CA | SER | B | 519 | 17.501 | 46.650 | 50.371 | 1.00 | 57.68 | B | C |
| ATOM | 3363 | CB | SER | B | 519 | 17.709 | 46.903 | 51.865 | 1.00 | 55.39 | B | C |
| ATOM | 3364 | OG | SER | B | 519 | 18.505 | 45.876 | 52.432 | 1.00 | 52.40 | B | O |
| ATOM | 3365 | C | SER | B | 519 | 16.823 | 45.301 | 50.160 | 1.00 | 58.66 | B | C |
| ATOM | 3366 | O | SER | B | 519 | 17.306 | 44.456 | 49.393 | 1.00 | 59.31 | B | O |
| ATOM | 3367 | N | GLY | B | 520 | 15.691 | 45.115 | 50.837 | 1.00 | 58.44 | B | N |
| ATOM | 3368 | CA | GLY | B | 520 | 14.943 | 43.876 | 50.724 | 1.00 | 57.10 | B | C |
| ATOM | 3369 | C | GLY | B | 520 | 15.356 | 42.821 | 51.734 | 1.00 | 56.14 | B | C |
| ATOM | 3370 | O | GLY | B | 520 | 14.540 | 41.996 | 52.143 | 1.00 | 56.59 | B | O |
| ATOM | 3371 | N | HIS | B | 521 | 16.619 | 42.850 | 52.145 | 1.00 | 55.30 | B | N |
| ATOM | 3372 | CA | HIS | B | 521 | 17.139 | 41.874 | 53.095 | 1.00 | 54.79 | B | C |
| ATOM | 3373 | CB | HIS | B | 521 | 18.268 | 41.070 | 52.435 | 1.00 | 57.61 | B | C |
| ATOM | 3374 | CG | HIS | B | 521 | 19.160 | 41.888 | 51.546 | 1.00 | 61.58 | B | C |
| ATOM | 3375 | CD2 | HIS | B | 521 | 19.830 | 43.045 | 51.773 | 1.00 | 62.72 | B | C |
| ATOM | 3376 | ND1 | HIS | B | 521 | 19.443 | 41.533 | 50.243 | 1.00 | 63.23 | B | N |
| ATOM | 3377 | CE1 | HIS | B | 521 | 20.247 | 42.435 | 49.705 | 1.00 | 65.34 | B | C |
| ATOM | 3378 | NE2 | HIS | B | 521 | 20.497 | 43.364 | 50.613 | 1.00 | 64.77 | B | N |
| ATOM | 3379 | C | HIS | B | 521 | 17.667 | 42.535 | 54.365 | 1.00 | 53.47 | B | C |
| ATOM | 3380 | O | HIS | B | 521 | 18.748 | 43.121 | 54.349 | 1.00 | 56.78 | B | O |
| ATOM | 3381 | N | MET | B | 522 | 16.929 | 42.444 | 55.468 | 1.00 | 50.18 | B | N |
| ATOM | 3382 | CA | MET | B | 522 | 17.418 | 43.058 | 56.697 | 1.00 | 50.20 | B | C |
| ATOM | 3383 | CB | MET | B | 522 | 16.293 | 43.744 | 57.468 | 1.00 | 51.09 | B | C |
| ATOM | 3384 | CG | MET | B | 522 | 16.767 | 45.016 | 58.161 | 1.00 | 54.15 | B | C |
| ATOM | 3385 | SD | MET | B | 522 | 16.287 | 45.140 | 59.902 | 1.00 | 60.57 | B | S |
| ATOM | 3386 | CE | MET | B | 522 | 14.512 | 45.424 | 59.725 | 1.00 | 58.43 | B | C |
| ATOM | 3387 | C | MET | B | 522 | 18.157 | 42.103 | 57.631 | 1.00 | 46.96 | B | C |
| ATOM | 3388 | O | MET | B | 522 | 17.904 | 40.895 | 57.653 | 1.00 | 46.06 | B | O |
| ATOM | 3389 | N | PHE | B | 523 | 19.077 | 42.681 | 58.398 | 1.00 | 42.56 | B | N |
| ATOM | 3390 | CA | PHE | B | 523 | 19.906 | 41.963 | 59.359 | 1.00 | 38.59 | B | C |
| ATOM | 3391 | CB | PHE | B | 523 | 20.576 | 42.977 | 60.287 | 1.00 | 35.69 | B | C |
| ATOM | 3392 | CG | PHE | B | 523 | 21.807 | 42.460 | 60.962 | 1.00 | 34.15 | B | C |
| ATOM | 3393 | CD1 | PHE | B | 523 | 22.781 | 41.779 | 60.238 | 1.00 | 31.37 | B | C |
| ATOM | 3394 | CD2 | PHE | B | 523 | 21.998 | 42.660 | 62.326 | 1.00 | 30.82 | B | C |
| ATOM | 3395 | CE1 | PHE | B | 523 | 23.929 | 41.304 | 60.864 | 1.00 | 31.32 | B | C |
| ATOM | 3396 | CE2 | PHE | B | 523 | 23.144 | 42.188 | 62.960 | 1.00 | 32.97 | B | C |
| ATOM | 3397 | CZ | PHE | B | 523 | 24.113 | 41.507 | 62.226 | 1.00 | 30.09 | B | C |
| ATOM | 3398 | C | PHE | B | 523 | 19.142 | 40.933 | 60.191 | 1.00 | 35.77 | B | C |
| ATOM | 3399 | O | PHE | B | 523 | 18.093 | 41.231 | 60.752 | 1.00 | 33.68 | B | O |
| ATOM | 3400 | N | SER | B | 524 | 19.688 | 39.725 | 60.278 | 1.00 | 34.49 | B | N |
| ATOM | 3401 | CA | SER | B | 524 | 19.064 | 38.655 | 61.043 | 1.00 | 35.12 | B | C |
| ATOM | 3402 | CB | SER | B | 524 | 17.915 | 38.045 | 60.242 | 1.00 | 35.33 | B | C |
| ATOM | 3403 | OG | SER | B | 524 | 18.193 | 36.697 | 59.897 | 1.00 | 35.72 | B | O |
| ATOM | 3404 | C | SER | B | 524 | 20.063 | 37.561 | 61.406 | 1.00 | 36.40 | B | C |
| ATOM | 3405 | O | SER | B | 524 | 21.234 | 37.621 | 61.037 | 1.00 | 38.17 | B | O |
| ATOM | 3406 | N | SER | B | 525 | 19.587 | 36.558 | 62.132 | 1.00 | 38.03 | B | N |
| ATOM | 3407 | CA | SER | B | 525 | 20.420 | 35.438 | 62.545 | 1.00 | 40.27 | B | C |
| ATOM | 3408 | CB | SER | B | 525 | 19.631 | 34.539 | 63.497 | 1.00 | 39.96 | B | C |
| ATOM | 3409 | OG | SER | B | 525 | 20.346 | 34.331 | 64.699 | 1.00 | 47.37 | B | O |
| ATOM | 3410 | C | SER | B | 525 | 20.861 | 34.623 | 61.330 | 1.00 | 40.84 | B | C |
| ATOM | 3411 | O | SER | B | 525 | 21.928 | 34.005 | 61.332 | 1.00 | 38.31 | B | O |
| ATOM | 3412 | N | LYS | B | 526 | 20.021 | 34.633 | 60.298 | 1.00 | 41.88 | B | N |
| ATOM | 3413 | CA | LYS | B | 526 | 20.275 | 33.897 | 59.065 | 1.00 | 40.92 | B | C |
| ATOM | 3414 | CB | LYS | B | 526 | 18.960 | 33.672 | 58.314 | 1.00 | 46.68 | B | C |
| ATOM | 3415 | CG | LYS | B | 526 | 17.760 | 33.382 | 59.206 | 1.00 | 51.67 | B | C |
| ATOM | 3416 | CD | LYS | B | 526 | 17.202 | 31.982 | 58.953 | 1.00 | 55.38 | B | C |
| ATOM | 3417 | CE | LYS | B | 526 | 15.692 | 31.923 | 59.200 | 1.00 | 59.23 | B | C |
| ATOM | 3418 | NZ | LYS | B | 526 | 14.957 | 31.192 | 58.118 | 1.00 | 60.30 | B | N |
| ATOM | 3419 | C | LYS | B | 526 | 21.266 | 34.585 | 58.131 | 1.00 | 38.32 | B | C |
| ATOM | 3420 | O | LYS | B | 526 | 21.943 | 33.923 | 57.344 | 1.00 | 38.57 | B | O |
| ATOM | 3421 | N | SER | B | 527 | 21.344 | 35.909 | 58.215 | 1.00 | 34.61 | B | N |
| ATOM | 3422 | CA | SER | B | 527 | 22.246 | 36.679 | 57.366 | 1.00 | 32.50 | B | C |
| ATOM | 3423 | CB | SER | B | 527 | 22.266 | 38.136 | 57.825 | 1.00 | 31.39 | B | C |
| ATOM | 3424 | OG | SER | B | 527 | 20.951 | 38.655 | 57.913 | 1.00 | 29.66 | B | O |
| ATOM | 3425 | C | SER | B | 527 | 23.669 | 36.117 | 57.359 | 1.00 | 31.51 | B | C |
| ATOM | 3426 | O | SER | B | 527 | 24.256 | 35.881 | 58.415 | 1.00 | 36.16 | B | O |
| ATOM | 3427 | N | PRO | B | 528 | 24.238 | 35.889 | 56.165 | 1.00 | 27.05 | B | N |
| ATOM | 3428 | CD | PRO | B | 528 | 23.642 | 36.109 | 54.837 | 1.00 | 26.60 | B | C |
| ATOM | 3429 | CA | PRO | B | 528 | 25.601 | 35.352 | 56.069 | 1.00 | 26.82 | B | C |
| ATOM | 3430 | CB | PRO | B | 528 | 25.823 | 35.183 | 54.566 | 1.00 | 26.91 | B | C |
| ATOM | 3431 | CG | PRO | B | 528 | 24.840 | 36.106 | 53.930 | 1.00 | 26.61 | B | C |
| ATOM | 3432 | C | PRO | B | 528 | 26.614 | 36.303 | 56.679 | 1.00 | 26.10 | B | C |
| ATOM | 3433 | O | PRO | B | 528 | 26.394 | 37.509 | 56.695 | 1.00 | 26.80 | B | O |
| ATOM | 3434 | N | LYS | B | 529 | 27.716 | 35.761 | 57.185 | 1.00 | 26.21 | B | N |
| ATOM | 3435 | CA | LYS | B | 529 | 28.749 | 36.595 | 57.779 | 1.00 | 26.56 | B | C |
| ATOM | 3436 | CB | LYS | B | 529 | 29.773 | 35.735 | 58.524 | 1.00 | 26.44 | B | C |
| ATOM | 3437 | CG | LYS | B | 529 | 29.170 | 34.792 | 59.560 | 1.00 | 28.45 | B | C |
| ATOM | 3438 | CD | LYS | B | 529 | 28.440 | 35.541 | 60.666 | 1.00 | 29.76 | B | C |
| ATOM | 3439 | CE | LYS | B | 529 | 27.114 | 34.864 | 60.998 | 1.00 | 33.50 | B | C |
| ATOM | 3440 | NZ | LYS | B | 529 | 27.050 | 34.424 | 62.420 | 1.00 | 33.70 | B | N |
| ATOM | 3441 | C | LYS | B | 529 | 29.418 | 37.354 | 56.642 | 1.00 | 26.57 | B | C |
| ATOM | 3442 | O | LYS | B | 529 | 29.292 | 36.969 | 55.482 | 1.00 | 29.09 | B | O |
| ATOM | 3443 | N | PRO | B | 530 | 30.129 | 38.447 | 56.955 | 1.00 | 26.82 | B | N |
| ATOM | 3444 | CD | PRO | B | 530 | 30.323 | 38.990 | 58.310 | 1.00 | 25.00 | B | C |
| ATOM | 3445 | CA | PRO | B | 530 | 30.814 | 39.260 | 55.942 | 1.00 | 27.60 | B | C |
| ATOM | 3446 | CB | PRO | B | 530 | 31.663 | 40.218 | 56.771 | 1.00 | 26.85 | B | C |
| ATOM | 3447 | CG | PRO | B | 530 | 30.907 | 40.349 | 58.049 | 1.00 | 27.09 | B | C |
| ATOM | 3448 | C | PRO | B | 530 | 31.654 | 38.473 | 54.931 | 1.00 | 30.93 | B | C |
| ATOM | 3449 | O | PRO | B | 530 | 31.608 | 38.753 | 53.725 | 1.00 | 32.07 | B | O |
| ATOM | 3450 | N | GLN | B | 531 | 32.421 | 37.501 | 55.420 | 1.00 | 30.94 | B | N |
| ATOM | 3451 | CA | GLN | B | 531 | 33.270 | 36.689 | 54.549 | 1.00 | 31.39 | B | C |
| ATOM | 3452 | CB | GLN | B | 531 | 34.252 | 35.855 | 55.379 | 1.00 | 31.62 | B | C |
| ATOM | 3453 | CG | GLN | B | 531 | 33.589 | 34.765 | 56.216 | 1.00 | 33.97 | B | C |
| ATOM | 3454 | CD | GLN | B | 531 | 33.235 | 35.232 | 57.624 | 1.00 | 35.00 | B | C |
| ATOM | 3455 | OE1 | GLN | B | 531 | 33.287 | 36.428 | 57.931 | 1.00 | 33.99 | B | O |
| ATOM | 3456 | NE2 | GLN | B | 531 | 32.873 | 34.285 | 58.487 | 1.00 | 33.70 | B | N |
| ATOM | 3457 | C | GLN | B | 531 | 32.429 | 35.763 | 53.681 | 1.00 | 28.81 | B | C |
| ATOM | 3458 | O | GLN | B | 531 | 32.893 | 35.287 | 52.651 | 1.00 | 29.84 | B | O |
| ATOM | 3459 | N | GLU | B | 532 | 31.196 | 35.508 | 54.102 | 1.00 | 27.20 | B | N |
| ATOM | 3460 | CA | GLU | B | 532 | 30.295 | 34.639 | 53.344 | 1.00 | 28.06 | B | C |
| ATOM | 3461 | CB | GLU | B | 532 | 29.386 | 33.859 | 54.292 | 1.00 | 28.56 | B | C |
| ATOM | 3462 | CG | GLU | B | 532 | 30.087 | 32.748 | 55.061 | 1.00 | 37.74 | B | C |
| ATOM | 3463 | CD | GLU | B | 532 | 29.373 | 32.394 | 56.363 | 1.00 | 44.00 | B | C |
| ATOM | 3464 | OE1 | GLU | B | 532 | 28.227 | 32.862 | 56.571 | 1.00 | 44.34 | B | O |
| ATOM | 3465 | OE2 | GLU | B | 532 | 29.960 | 31.647 | 57.179 | 1.00 | 46.78 | B | O |
| ATOM | 3466 | C | GLU | B | 532 | 29.438 | 35.452 | 52.372 | 1.00 | 28.77 | B | C |
| ATOM | 3467 | O | GLU | B | 532 | 28.743 | 34.896 | 51.519 | 1.00 | 26.75 | B | O |
| ATOM | 3468 | N | TRP | B | 533 | 29.487 | 36.774 | 52.510 | 1.00 | 27.66 | B | N |
| ATOM | 3469 | CA | TRP | B | 533 | 28.725 | 37.661 | 51.643 | 1.00 | 24.08 | B | C |
| ATOM | 3470 | CB | TRP | B | 533 | 28.505 | 39.009 | 52.329 | 1.00 | 24.73 | B | C |
| ATOM | 3471 | CG | TRP | B | 533 | 27.503 | 39.863 | 51.624 | 1.00 | 24.65 | B | C |
| ATOM | 3472 | CD2 | TRP | B | 533 | 26.139 | 40.081 | 52.010 | 1.00 | 24.36 | B | C |
| ATOM | 3473 | CE2 | TRP | B | 533 | 25.557 | 40.914 | 51.034 | 1.00 | 23.05 | B | C |
| ATOM | 3474 | CE3 | TRP | B | 533 | 25.354 | 39.649 | 53.089 | 1.00 | 26.11 | B | C |
| ATOM | 3475 | CD1 | TRP | B | 533 | 27.688 | 40.557 | 50.463 | 1.00 | 22.13 | B | C |
| ATOM | 3476 | NE1 | TRP | B | 533 | 26.523 | 41.190 | 50.101 | 1.00 | 23.27 | B | N |
| ATOM | 3477 | CZ2 | TRP | B | 533 | 24.223 | 41.327 | 51.099 | 1.00 | 23.97 | B | C |
| ATOM | 3478 | CZ3 | TRP | B | 533 | 24.024 | 40.060 | 53.157 | 1.00 | 24.84 | B | C |
| ATOM | 3479 | CH2 | TRP | B | 533 | 23.473 | 40.890 | 52.163 | 1.00 | 24.39 | B | C |
| ATOM | 3480 | C | TRP | B | 533 | 29.499 | 37.867 | 50.356 | 1.00 | 22.94 | B | C |
| ATOM | 3481 | O | TRP | B | 533 | 30.190 | 38.872 | 50.193 | 1.00 | 20.80 | B | O |
| ATOM | 3482 | N | THR | B | 534 | 29.380 | 36.908 | 49.445 | 1.00 | 24.93 | B | N |
| ATOM | 3483 | CA | THR | B | 534 | 30.086 | 36.969 | 48.168 | 1.00 | 25.58 | B | C |
| ATOM | 3484 | CB | THR | B | 534 | 30.607 | 35.585 | 47.784 | 1.00 | 24.41 | B | C |
| ATOM | 3485 | OG1 | THR | B | 534 | 29.518 | 34.657 | 47.809 | 1.00 | 26.54 | B | O |
| ATOM | 3486 | CG2 | THR | B | 534 | 31.675 | 35.122 | 48.768 | 1.00 | 23.45 | B | C |
| ATOM | 3487 | C | THR | B | 534 | 29.230 | 37.500 | 47.017 | 1.00 | 23.91 | B | C |
| ATOM | 3488 | O | THR | B | 534 | 29.752 | 37.800 | 45.945 | 1.00 | 21.11 | B | O |
| ATOM | 3489 | N | LEU | B | 535 | 27.923 | 37.614 | 47.237 | 1.00 | 25.95 | B | N |
| ATOM | 3490 | CA | LEU | B | 535 | 27.021 | 38.115 | 46.204 | 1.00 | 27.99 | B | C |
| ATOM | 3491 | CB | LEU | B | 535 | 25.564 | 37.853 | 46.592 | 1.00 | 29.58 | B | C |
| ATOM | 3492 | CG | LEU | B | 535 | 25.128 | 38.219 | 48.012 | 1.00 | 35.55 | B | C |
| ATOM | 3493 | CD1 | LEU | B | 535 | 23.722 | 38.789 | 47.968 | 1.00 | 34.40 | B | C |
| ATOM | 3494 | CD2 | LEU | B | 535 | 25.176 | 36.982 | 48.919 | 1.00 | 39.00 | B | C |
| ATOM | 3495 | C | LEU | B | 535 | 27.244 | 39.605 | 45.932 | 1.00 | 27.19 | B | C |
| ATOM | 3496 | O | LEU | B | 535 | 27.937 | 40.294 | 46.681 | 1.00 | 28.05 | B | O |
| ATOM | 3497 | N | GLU | B | 536 | 26.659 | 40.097 | 44.850 | 1.00 | 29.59 | B | N |
| ATOM | 3498 | CA | GLU | B | 536 | 26.831 | 41.492 | 44.461 | 1.00 | 33.34 | B | C |
| ATOM | 3499 | CB | GLU | B | 536 | 26.566 | 41.642 | 42.963 | 1.00 | 36.71 | B | C |
| ATOM | 3500 | CG | GLU | B | 536 | 27.679 | 42.350 | 42.209 | 1.00 | 45.22 | B | C |
| ATOM | 3501 | CD | GLU | B | 536 | 27.547 | 42.204 | 40.700 | 1.00 | 49.84 | B | C |
| ATOM | 3502 | OE1 | GLU | B | 536 | 26.906 | 43.077 | 40.067 | 1.00 | 51.71 | B | O |
| ATOM | 3503 | OE2 | GLU | B | 536 | 28.083 | 41.217 | 40.149 | 1.00 | 49.45 | B | O |
| ATOM | 3504 | C | GLU | B | 536 | 25.966 | 42.484 | 45.226 | 1.00 | 30.48 | B | C |
| ATOM | 3505 | O | GLU | B | 536 | 26.301 | 43.664 | 45.311 | 1.00 | 28.73 | B | O |
| ATOM | 3506 | N | LYS | B | 537 | 24.855 | 42.004 | 45.774 | 1.00 | 30.76 | B | N |
| ATOM | 3507 | CA | LYS | B | 537 | 23.929 | 42.847 | 46.529 | 1.00 | 30.68 | B | C |
| ATOM | 3508 | CB | LYS | B | 537 | 22.846 | 41.984 | 47.182 | 1.00 | 35.47 | B | C |
| ATOM | 3509 | CG | LYS | B | 537 | 21.545 | 41.909 | 46.404 | 1.00 | 41.42 | B | C |
| ATOM | 3510 | CD | LYS | B | 537 | 20.841 | 43.262 | 46.369 | 1.00 | 47.30 | B | C |
| ATOM | 3511 | CE | LYS | B | 537 | 19.584 | 43.214 | 45.499 | 1.00 | 51.32 | B | C |
| ATOM | 3512 | NZ | LYS | B | 537 | 18.965 | 44.561 | 45.301 | 1.00 | 51.33 | B | N |
| ATOM | 3513 | C | LYS | B | 537 | 24.630 | 43.649 | 47.617 | 1.00 | 28.84 | B | C |
| ATOM | 3514 | O | LYS | B | 537 | 25.535 | 43.144 | 48.285 | 1.00 | 27.96 | B | O |
| ATOM | 3515 | N | ASN | B | 538 | 24.222 | 44.903 | 47.790 | 1.00 | 26.11 | B | N |
| ATOM | 3516 | CA | ASN | B | 538 | 24.811 | 45.729 | 48.840 | 1.00 | 24.48 | B | C |
| ATOM | 3517 | CB | ASN | B | 538 | 24.624 | 47.219 | 48.550 | 1.00 | 22.50 | B | C |
| ATOM | 3518 | CG | ASN | B | 538 | 25.683 | 48.078 | 49.221 | 1.00 | 21.82 | B | C |
| ATOM | 3519 | OD1 | ASN | B | 538 | 26.731 | 47.579 | 49.637 | 1.00 | 19.97 | B | O |
| ATOM | 3520 | ND2 | ASN | B | 538 | 25.415 | 49.380 | 49.327 | 1.00 | 18.82 | B | N |
| ATOM | 3521 | C | ASN | B | 538 | 24.081 | 45.368 | 50.126 | 1.00 | 23.84 | B | C |
| ATOM | 3522 | O | ASN | B | 538 | 22.848 | 45.316 | 50.151 | 1.00 | 22.60 | B | O |
| ATOM | 3523 | N | PRO | B | 539 | 24.828 | 45.089 | 51.206 | 1.00 | 23.09 | B | N |
| ATOM | 3524 | CD | PRO | B | 539 | 26.296 | 45.073 | 51.332 | 1.00 | 22.30 | B | C |
| ATOM | 3525 | CA | PRO | B | 539 | 24.165 | 44.737 | 52.466 | 1.00 | 21.96 | B | C |
| ATOM | 3526 | CB | PRO | B | 539 | 25.326 | 44.480 | 53.432 | 1.00 | 21.38 | B | C |
| ATOM | 3527 | CG | PRO | B | 539 | 26.517 | 44.232 | 52.554 | 1.00 | 20.53 | B | C |
| ATOM | 3528 | C | PRO | B | 539 | 23.269 | 45.881 | 52.930 | 1.00 | 19.85 | B | C |
| ATOM | 3529 | O | PRO | B | 539 | 23.456 | 47.021 | 52.509 | 1.00 | 18.60 | B | O |
| ATOM | 3530 | N | SER | B | 540 | 22.296 | 45.572 | 53.785 | 1.00 | 18.60 | B | N |
| ATOM | 3531 | CA | SER | B | 540 | 21.380 | 46.583 | 54.305 | 1.00 | 16.03 | B | C |
| ATOM | 3532 | CB | SER | B | 540 | 20.262 | 45.917 | 55.119 | 1.00 | 15.58 | B | C |
| ATOM | 3533 | OG | SER | B | 540 | 20.692 | 45.575 | 56.423 | 1.00 | 18.82 | B | O |
| ATOM | 3534 | C | SER | B | 540 | 22.117 | 47.604 | 55.168 | 1.00 | 15.23 | B | C |
| ATOM | 3535 | O | SER | B | 540 | 23.277 | 47.409 | 55.530 | 1.00 | 14.29 | B | O |
| ATOM | 3536 | N | TYR | B | 541 | 21.435 | 48.697 | 55.488 | 1.00 | 15.23 | B | N |
| ATOM | 3537 | CA | TYR | B | 541 | 22.009 | 49.758 | 56.304 | 1.00 | 16.19 | B | C |
| ATOM | 3538 | CB | TYR | B | 541 | 20.974 | 50.879 | 56.487 | 1.00 | 17.18 | B | C |
| ATOM | 3539 | CG | TYR | B | 541 | 21.405 | 52.027 | 57.386 | 1.00 | 17.28 | B | C |
| ATOM | 3540 | CD1 | TYR | B | 541 | 21.232 | 51.956 | 58.770 | 1.00 | 15.35 | B | C |
| ATOM | 3541 | CE1 | TYR | B | 541 | 21.607 | 53.014 | 59.601 | 1.00 | 15.34 | B | C |
| ATOM | 3542 | CD2 | TYR | B | 541 | 21.968 | 53.190 | 56.850 | 1.00 | 14.03 | B | C |
| ATOM | 3543 | CE2 | TYR | B | 541 | 22.350 | 54.259 | 57.671 | 1.00 | 12.17 | B | C |
| ATOM | 3544 | CZ | TYR | B | 541 | 22.164 | 54.162 | 59.047 | 1.00 | 15.72 | B | C |
| ATOM | 3545 | OH | TYR | B | 541 | 22.519 | 55.205 | 59.869 | 1.00 | 12.50 | B | O |
| ATOM | 3546 | C | TYR | B | 541 | 22.441 | 49.207 | 57.664 | 1.00 | 17.66 | B | C |
| ATOM | 3547 | O | TYR | B | 541 | 23.540 | 49.487 | 58.143 | 1.00 | 17.01 | B | O |
| ATOM | 3548 | N | THR | B | 542 | 21.568 | 48.410 | 58.273 | 1.00 | 19.06 | B | N |
| ATOM | 3549 | CA | THR | B | 542 | 21.824 | 47.829 | 59.588 | 1.00 | 18.23 | B | C |
| ATOM | 3550 | CB | THR | B | 542 | 20.555 | 47.136 | 60.109 | 1.00 | 18.52 | B | C |
| ATOM | 3551 | OG1 | THR | B | 542 | 19.511 | 48.111 | 60.221 | 1.00 | 18.24 | B | O |
| ATOM | 3552 | CG2 | THR | B | 542 | 20.794 | 46.509 | 61.472 | 1.00 | 19.19 | B | C |
| ATOM | 3553 | C | THR | B | 542 | 23.001 | 46.857 | 59.600 | 1.00 | 18.38 | B | C |
| ATOM | 3554 | O | THR | B | 542 | 23.710 | 46.745 | 60.602 | 1.00 | 17.95 | B | O |
| ATOM | 3555 | N | TYR | B | 543 | 23.202 | 46.154 | 58.490 | 1.00 | 16.93 | B | N |
| ATOM | 3556 | CA | TYR | B | 543 | 24.314 | 45.220 | 58.362 | 1.00 | 16.68 | B | C |
| ATOM | 3557 | CB | TYR | B | 543 | 24.234 | 44.511 | 57.009 | 1.00 | 17.16 | B | C |
| ATOM | 3558 | CG | TYR | B | 543 | 25.124 | 43.303 | 56.863 | 1.00 | 14.93 | B | C |
| ATOM | 3559 | CD1 | TYR | B | 543 | 26.446 | 43.437 | 56.456 | 1.00 | 15.90 | B | C |
| ATOM | 3560 | CE1 | TYR | B | 543 | 27.261 | 42.318 | 56.264 | 1.00 | 19.59 | B | C |
| ATOM | 3561 | CD2 | TYR | B | 543 | 24.630 | 42.018 | 57.081 | 1.00 | 18.53 | B | C |
| ATOM | 3562 | CE2 | TYR | B | 543 | 25.436 | 40.887 | 56.893 | 1.00 | 20.68 | B | C |
| ATOM | 3563 | CZ | TYR | B | 543 | 26.752 | 41.050 | 56.480 | 1.00 | 19.68 | B | C |
| ATOM | 3564 | OH | TYR | B | 543 | 27.553 | 39.954 | 56.262 | 1.00 | 20.00 | B | O |
| ATOM | 3565 | C | TYR | B | 543 | 25.597 | 46.045 | 58.450 | 1.00 | 16.46 | B | C |
| ATOM | 3566 | O | TYR | B | 543 | 26.523 | 45.716 | 59.192 | 1.00 | 17.20 | B | O |
| ATOM | 3567 | N | TYR | B | 544 | 25.643 | 47.126 | 57.683 | 1.00 | 16.33 | B | N |
| ATOM | 3568 | CA | TYR | B | 544 | 26.798 | 48.015 | 57.686 | 1.00 | 19.32 | B | C |
| ATOM | 3569 | CB | TYR | B | 544 | 26.550 | 49.202 | 56.748 | 1.00 | 16.57 | B | C |
| ATOM | 3570 | CG | TYR | B | 544 | 27.031 | 49.034 | 55.325 | 1.00 | 17.46 | B | C |
| ATOM | 3571 | CD1 | TYR | B | 544 | 26.184 | 48.529 | 54.334 | 1.00 | 17.00 | B | C |
| ATOM | 3572 | CE1 | TYR | B | 544 | 26.589 | 48.471 | 52.997 | 1.00 | 18.05 | B | C |
| ATOM | 3573 | CD2 | TYR | B | 544 | 28.301 | 49.469 | 54.945 | 1.00 | 17.93 | B | C |
| ATOM | 3574 | CE2 | TYR | B | 544 | 28.715 | 49.414 | 53.614 | 1.00 | 19.86 | B | C |
| ATOM | 3575 | CZ | TYR | B | 544 | 27.855 | 48.923 | 52.645 | 1.00 | 20.49 | B | C |
| ATOM | 3576 | OH | TYR | B | 544 | 28.257 | 48.920 | 51.324 | 1.00 | 20.58 | B | O |
| ATOM | 3577 | C | TYR | B | 544 | 27.004 | 48.550 | 59.112 | 1.00 | 21.01 | B | C |
| ATOM | 3578 | O | TYR | B | 544 | 28.086 | 48.425 | 59.697 | 1.00 | 23.05 | B | O |
| ATOM | 3579 | N | ALA | B | 545 | 25.948 | 49.156 | 59.652 | 1.00 | 21.73 | B | N |
| ATOM | 3580 | CA | ALA | B | 545 | 25.963 | 49.739 | 60.983 | 1.00 | 20.34 | B | C |
| ATOM | 3581 | CB | ALA | B | 545 | 24.570 | 50.242 | 61.343 | 1.00 | 21.34 | B | C |
| ATOM | 3582 | C | ALA | B | 545 | 26.456 | 48.781 | 62.055 | 1.00 | 20.95 | B | C |
| ATOM | 3583 | O | ALA | B | 545 | 27.325 | 49.138 | 62.854 | 1.00 | 21.84 | B | O |
| ATOM | 3584 | N | TYR | B | 546 | 25.919 | 47.565 | 62.086 | 1.00 | 19.26 | B | N |
| ATOM | 3585 | CA | TYR | B | 546 | 26.351 | 46.621 | 63.107 | 1.00 | 18.59 | B | C |
| ATOM | 3586 | CB | TYR | B | 546 | 25.603 | 45.291 | 63.008 | 1.00 | 19.97 | B | C |
| ATOM | 3587 | CG | TYR | B | 546 | 26.127 | 44.287 | 64.019 | 1.00 | 22.12 | B | C |
| ATOM | 3588 | CD1 | TYR | B | 546 | 25.686 | 44.314 | 65.342 | 1.00 | 26.12 | B | C |
| ATOM | 3589 | CE1 | TYR | B | 546 | 26.235 | 43.468 | 66.306 | 1.00 | 25.63 | B | C |
| ATOM | 3590 | CD2 | TYR | B | 546 | 27.128 | 43.378 | 63.682 | 1.00 | 21.94 | B | C |
| ATOM | 3591 | CE2 | TYR | B | 546 | 27.684 | 42.528 | 64.637 | 1.00 | 23.91 | B | C |
| ATOM | 3592 | CZ | TYR | B | 546 | 27.234 | 42.585 | 65.948 | 1.00 | 25.98 | B | C |
| ATOM | 3593 | OH | TYR | B | 546 | 27.805 | 41.785 | 66.908 | 1.00 | 27.63 | B | O |
| ATOM | 3594 | C | TYR | B | 546 | 27.845 | 46.326 | 63.069 | 1.00 | 18.62 | B | C |
| ATOM | 3595 | O | TYR | B | 546 | 28.533 | 46.437 | 64.082 | 1.00 | 17.72 | B | O |
| ATOM | 3596 | N | TYR | B | 547 | 28.349 | 45.947 | 61.899 | 1.00 | 18.97 | B | N |
| ATOM | 3597 | CA | TYR | B | 547 | 29.756 | 45.602 | 61.770 | 1.00 | 16.59 | B | C |
| ATOM | 3598 | CB | TYR | B | 547 | 29.984 | 44.891 | 60.439 | 1.00 | 16.13 | B | C |
| ATOM | 3599 | CG | TYR | B | 547 | 29.488 | 43.468 | 60.507 | 1.00 | 13.73 | B | C |
| ATOM | 3600 | CD1 | TYR | B | 547 | 30.179 | 42.509 | 61.244 | 1.00 | 12.30 | B | C |
| ATOM | 3601 | CE1 | TYR | B | 547 | 29.690 | 41.219 | 61.383 | 1.00 | 13.15 | B | C |
| ATOM | 3602 | CD2 | TYR | B | 547 | 28.293 | 43.096 | 59.903 | 1.00 | 10.74 | B | C |
| ATOM | 3603 | CE2 | TYR | B | 547 | 27.796 | 41.804 | 60.037 | 1.00 | 12.96 | B | C |
| ATOM | 3604 | CZ | TYR | B | 547 | 28.500 | 40.872 | 60.779 | 1.00 | 13.29 | B | C |
| ATOM | 3605 | OH | TYR | B | 547 | 28.024 | 39.589 | 60.912 | 1.00 | 15.26 | B | O |
| ATOM | 3606 | C | TYR | B | 547 | 30.720 | 46.755 | 61.958 | 1.00 | 16.86 | B | C |
| ATOM | 3607 | O | TYR | B | 547 | 31.894 | 46.544 | 62.280 | 1.00 | 17.63 | B | O |
| ATOM | 3608 | N | MET | B | 548 | 30.232 | 47.973 | 61.770 | 1.00 | 16.37 | B | N |
| ATOM | 3609 | CA | MET | B | 548 | 31.072 | 49.139 | 61.973 | 1.00 | 18.11 | B | C |
| ATOM | 3610 | CB | MET | B | 548 | 30.490 | 50.342 | 61.236 | 1.00 | 18.30 | B | C |
| ATOM | 3611 | CG | MET | B | 548 | 31.044 | 50.501 | 59.835 | 1.00 | 19.81 | B | C |
| ATOM | 3612 | SD | MET | B | 548 | 30.693 | 52.116 | 59.156 | 1.00 | 32.45 | B | S |
| ATOM | 3613 | CE | MET | B | 548 | 32.084 | 53.075 | 59.789 | 1.00 | 24.56 | B | C |
| ATOM | 3614 | C | MET | B | 548 | 31.109 | 49.395 | 63.481 | 1.00 | 19.79 | B | C |
| ATOM | 3615 | O | MET | B | 548 | 32.146 | 49.741 | 64.044 | 1.00 | 19.28 | B | O |
| ATOM | 3616 | N | TYR | B | 549 | 29.969 | 49.203 | 64.137 | 1.00 | 20.86 | B | N |
| ATOM | 3617 | CA | TYR | B | 549 | 29.889 | 49.396 | 65.576 | 1.00 | 19.49 | B | C |
| ATOM | 3618 | CB | TYR | B | 549 | 28.447 | 49.223 | 66.059 | 1.00 | 19.22 | B | C |
| ATOM | 3619 | CG | TYR | B | 549 | 28.320 | 49.059 | 67.565 | 1.00 | 19.24 | B | C |
| ATOM | 3620 | CD1 | TYR | B | 549 | 28.301 | 50.173 | 68.403 | 1.00 | 18.57 | B | C |
| ATOM | 3621 | CE1 | TYR | B | 549 | 28.197 | 50.034 | 69.789 | 1.00 | 18.15 | B | C |
| ATOM | 3622 | CD2 | TYR | B | 549 | 28.233 | 47.791 | 68.151 | 1.00 | 15.94 | B | C |
| ATOM | 3623 | CE2 | TYR | B | 549 | 28.129 | 47.643 | 69.534 | 1.00 | 16.60 | B | C |
| ATOM | 3624 | CZ | TYR | B | 549 | 28.113 | 48.771 | 70.347 | 1.00 | 18.54 | B | C |
| ATOM | 3625 | OH | TYR | B | 549 | 28.016 | 48.642 | 71.718 | 1.00 | 19.16 | B | O |
| ATOM | 3626 | C | TYR | B | 549 | 30.775 | 48.367 | 66.262 | 1.00 | 19.65 | B | C |
| ATOM | 3627 | O | TYR | B | 549 | 31.571 | 48.701 | 67.139 | 1.00 | 20.48 | B | O |
| ATOM | 3628 | N | ALA | B | 550 | 30.623 | 47.111 | 65.849 | 1.00 | 20.12 | B | N |
| ATOM | 3629 | CA | ALA | B | 550 | 31.375 | 45.998 | 66.420 | 1.00 | 18.54 | B | C |
| ATOM | 3630 | CB | ALA | B | 550 | 31.016 | 44.709 | 65.688 | 1.00 | 16.58 | B | C |
| ATOM | 3631 | C | ALA | B | 550 | 32.886 | 46.215 | 66.400 | 1.00 | 18.28 | B | C |
| ATOM | 3632 | O | ALA | B | 550 | 33.555 | 46.079 | 67.425 | 1.00 | 16.51 | B | O |
| ATOM | 3633 | N | ASN | B | 551 | 33.426 | 46.554 | 65.236 | 1.00 | 18.75 | B | N |
| ATOM | 3634 | CA | ASN | B | 551 | 34.861 | 46.778 | 65.111 | 1.00 | 18.46 | B | C |
| ATOM | 3635 | CB | ASN | B | 551 | 35.243 | 46.902 | 63.634 | 1.00 | 18.01 | B | C |
| ATOM | 3636 | CG | ASN | B | 551 | 35.409 | 45.552 | 62.960 | 1.00 | 17.28 | B | C |
| ATOM | 3637 | OD1 | ASN | B | 551 | 34.524 | 45.098 | 62.236 | 1.00 | 16.26 | B | O |
| ATOM | 3638 | ND2 | ASN | B | 551 | 36.546 | 44.902 | 63.197 | 1.00 | 13.84 | B | N |
| ATOM | 3639 | C | ASN | B | 551 | 35.309 | 48.026 | 65.873 | 1.00 | 17.29 | B | C |
| ATOM | 3640 | O | ASN | B | 551 | 36.386 | 48.049 | 66.456 | 1.00 | 19.02 | B | O |
| ATOM | 3641 | N | ILE | B | 552 | 34.476 | 49.061 | 65.865 | 1.00 | 19.05 | B | N |
| ATOM | 3642 | CA | ILE | B | 552 | 34.791 | 50.306 | 66.558 | 1.00 | 17.24 | B | C |
| ATOM | 3643 | CB | ILE | B | 552 | 33.754 | 51.416 | 66.212 | 1.00 | 17.35 | B | C |
| ATOM | 3644 | CG2 | ILE | B | 552 | 33.881 | 52.593 | 67.185 | 1.00 | 12.67 | B | C |
| ATOM | 3645 | CG1 | ILE | B | 552 | 33.985 | 51.907 | 64.774 | 1.00 | 16.81 | B | C |
| ATOM | 3646 | CD1 | ILE | B | 552 | 33.045 | 53.012 | 64.328 | 1.00 | 13.53 | B | C |
| ATOM | 3647 | C | ILE | B | 552 | 34.819 | 50.067 | 68.066 | 1.00 | 18.52 | B | C |
| ATOM | 3648 | O | ILE | B | 552 | 35.665 | 50.616 | 68.780 | 1.00 | 17.63 | B | O |
| ATOM | 3649 | N | MET | B | 553 | 33.900 | 49.236 | 68.547 | 1.00 | 18.36 | B | N |
| ATOM | 3650 | CA | MET | B | 553 | 33.835 | 48.926 | 69.971 | 1.00 | 19.52 | B | C |
| ATOM | 3651 | CB | MET | B | 553 | 32.642 | 48.019 | 70.268 | 1.00 | 18.86 | B | C |
| ATOM | 3652 | CG | MET | B | 553 | 32.664 | 47.463 | 71.673 | 1.00 | 20.87 | B | C |
| ATOM | 3653 | SD | MET | B | 553 | 31.636 | 46.019 | 71.877 | 1.00 | 25.44 | B | S |
| ATOM | 3654 | CE | MET | B | 553 | 32.822 | 44.893 | 72.580 | 1.00 | 27.55 | B | C |
| ATOM | 3655 | C | MET | B | 553 | 35.113 | 48.243 | 70.448 | 1.00 | 20.15 | B | C |
| ATOM | 3656 | O | MET | B | 553 | 35.712 | 48.644 | 71.448 | 1.00 | 21.53 | B | O |
| ATOM | 3657 | N | VAL | B | 554 | 35.517 | 47.198 | 69.733 | 1.00 | 19.59 | B | N |
| ATOM | 3658 | CA | VAL | B | 554 | 36.723 | 46.459 | 70.074 | 1.00 | 19.21 | B | C |
| ATOM | 3659 | CB | VAL | B | 554 | 36.910 | 45.248 | 69.129 | 1.00 | 20.35 | B | C |
| ATOM | 3660 | CG1 | VAL | B | 554 | 38.131 | 44.429 | 69.555 | 1.00 | 22.79 | B | C |
| ATOM | 3661 | CG2 | VAL | B | 554 | 35.658 | 44.381 | 69.141 | 1.00 | 12.71 | B | C |
| ATOM | 3662 | C | VAL | B | 554 | 37.922 | 47.398 | 69.953 | 1.00 | 19.82 | B | C |
| ATOM | 3663 | O | VAL | B | 554 | 38.754 | 47.489 | 70.854 | 1.00 | 21.99 | B | O |
| ATOM | 3664 | N | LEU | B | 555 | 38.002 | 48.112 | 68.839 | 1.00 | 19.23 | B | N |
| ATOM | 3665 | CA | LEU | B | 555 | 39.100 | 49.047 | 68.626 | 1.00 | 19.76 | B | C |
| ATOM | 3666 | CB | LEU | B | 555 | 38.893 | 49.804 | 67.305 | 1.00 | 17.30 | B | C |
| ATOM | 3667 | CG | LEU | B | 555 | 39.831 | 50.961 | 66.937 | 1.00 | 15.22 | B | C |
| ATOM | 3668 | CD1 | LEU | B | 555 | 41.255 | 50.462 | 66.781 | 1.00 | 12.49 | B | C |
| ATOM | 3669 | CD2 | LEU | B | 555 | 39.349 | 51.595 | 65.640 | 1.00 | 12.74 | B | C |
| ATOM | 3670 | C | LEU | B | 555 | 39.184 | 50.045 | 69.782 | 1.00 | 20.30 | B | C |
| ATOM | 3671 | O | LEU | B | 555 | 40.272 | 50.446 | 70.194 | 1.00 | 17.85 | B | O |
| ATOM | 3672 | N | ASN | B | 556 | 38.026 | 50.443 | 70.302 | 1.00 | 19.94 | B | N |
| ATOM | 3673 | CA | ASN | B | 556 | 37.978 | 51.411 | 71.386 | 1.00 | 20.05 | B | C |
| ATOM | 3674 | CB | ASN | B | 556 | 36.553 | 51.957 | 71.525 | 1.00 | 20.14 | B | C |
| ATOM | 3675 | CG | ASN | B | 556 | 36.293 | 53.160 | 70.615 | 1.00 | 20.72 | B | C |
| ATOM | 3676 | OD1 | ASN | B | 556 | 37.220 | 53.723 | 70.019 | 1.00 | 17.57 | B | O |
| ATOM | 3677 | ND2 | ASN | B | 556 | 35.028 | 53.561 | 70.511 | 1.00 | 19.17 | B | N |
| ATOM | 3678 | C | ASN | B | 556 | 38.467 | 50.842 | 72.719 | 1.00 | 20.06 | B | C |
| ATOM | 3679 | O | ASN | B | 556 | 39.144 | 51.531 | 73.479 | 1.00 | 17.15 | B | O |
| ATOM | 3680 | N | SER | B | 557 | 38.128 | 49.585 | 72.995 | 1.00 | 22.57 | B | N |
| ATOM | 3681 | CA | SER | B | 557 | 38.556 | 48.938 | 74.232 | 1.00 | 25.43 | B | C |
| ATOM | 3682 | CB | SER | B | 557 | 37.980 | 47.520 | 74.329 | 1.00 | 25.65 | B | C |
| ATOM | 3683 | OG | SER | B | 557 | 36.565 | 47.527 | 74.262 | 1.00 | 28.24 | B | O |
| ATOM | 3684 | C | SER | B | 557 | 40.079 | 48.859 | 74.247 | 1.00 | 26.49 | B | C |
| ATOM | 3685 | O | SER | B | 557 | 40.725 | 49.184 | 75.248 | 1.00 | 29.87 | B | O |
| ATOM | 3686 | N | LEU | B | 558 | 40.643 | 48.425 | 73.126 | 1.00 | 24.95 | B | N |
| ATOM | 3687 | CA | LEU | B | 558 | 42.084 | 48.288 | 72.982 | 1.00 | 22.99 | B | C |
| ATOM | 3688 | CB | LEU | B | 558 | 42.403 | 47.669 | 71.621 | 1.00 | 25.68 | B | C |
| ATOM | 3689 | CG | LEU | B | 558 | 43.875 | 47.507 | 71.244 | 1.00 | 28.42 | B | C |
| ATOM | 3690 | CD1 | LEU | B | 558 | 44.526 | 46.471 | 72.144 | 1.00 | 28.63 | B | C |
| ATOM | 3691 | CD2 | LEU | B | 558 | 43.978 | 47.087 | 69.787 | 1.00 | 27.76 | B | C |
| ATOM | 3692 | C | LEU | B | 558 | 42.832 | 49.606 | 73.141 | 1.00 | 22.88 | B | C |
| ATOM | 3693 | O | LEU | B | 558 | 43.805 | 49.678 | 73.880 | 1.00 | 26.62 | B | O |
| ATOM | 3694 | N | ARG | B | 559 | 42.382 | 50.647 | 72.453 | 1.00 | 22.32 | B | N |
| ATOM | 3695 | CA | ARG | B | 559 | 43.033 | 51.953 | 72.527 | 1.00 | 22.79 | B | C |
| ATOM | 3696 | CB | ARG | B | 559 | 42.451 | 52.889 | 71.470 | 1.00 | 21.84 | B | C |
| ATOM | 3697 | CG | ARG | B | 559 | 43.146 | 52.788 | 70.116 | 1.00 | 20.93 | B | C |
| ATOM | 3698 | CD | ARG | B | 559 | 42.503 | 53.710 | 69.093 | 1.00 | 17.83 | B | C |
| ATOM | 3699 | NE | ARG | B | 559 | 43.206 | 54.981 | 68.971 | 1.00 | 17.24 | B | N |
| ATOM | 3700 | CZ | ARG | B | 559 | 44.377 | 55.132 | 68.361 | 1.00 | 15.20 | B | C |
| ATOM | 3701 | NH1 | ARG | B | 559 | 44.984 | 54.089 | 67.816 | 1.00 | 14.49 | B | N |
| ATOM | 3702 | NH2 | ARG | B | 559 | 44.933 | 56.329 | 68.279 | 1.00 | 11.89 | B | N |
| ATOM | 3703 | C | ARG | B | 559 | 42.903 | 52.606 | 73.896 | 1.00 | 26.31 | B | C |
| ATOM | 3704 | O | ARG | B | 559 | 43.763 | 53.386 | 74.308 | 1.00 | 27.24 | B | O |
| ATOM | 3705 | N | LYS | B | 560 | 41.815 | 52.298 | 74.591 | 1.00 | 29.53 | B | N |
| ATOM | 3706 | CA | LYS | B | 560 | 41.579 | 52.845 | 75.917 | 1.00 | 30.55 | B | C |
| ATOM | 3707 | CB | LYS | B | 560 | 40.207 | 52.402 | 76.437 | 1.00 | 34.05 | B | C |
| ATOM | 3708 | CG | LYS | B | 560 | 39.914 | 52.801 | 77.881 | 1.00 | 36.43 | B | C |
| ATOM | 3709 | CD | LYS | B | 560 | 39.179 | 54.136 | 77.957 | 1.00 | 39.20 | B | C |
| ATOM | 3710 | CE | LYS | B | 560 | 38.638 | 54.401 | 79.368 | 1.00 | 40.37 | B | C |
| ATOM | 3711 | NZ | LYS | B | 560 | 37.846 | 55.670 | 79.481 | 1.00 | 34.49 | B | N |
| ATOM | 3712 | C | LYS | B | 560 | 42.669 | 52.312 | 76.824 | 1.00 | 32.01 | B | C |
| ATOM | 3713 | O | LYS | B | 560 | 43.330 | 53.070 | 77.534 | 1.00 | 33.04 | B | O |
| ATOM | 3714 | N | GLU | B | 561 | 42.858 | 50.998 | 76.780 | 1.00 | 32.51 | B | N |
| ATOM | 3715 | CA | GLU | B | 561 | 43.870 | 50.336 | 77.587 | 1.00 | 34.59 | B | C |
| ATOM | 3716 | CB | GLU | B | 561 | 43.807 | 48.828 | 77.367 | 1.00 | 37.66 | B | C |
| ATOM | 3717 | CG | GLU | B | 561 | 42.951 | 48.099 | 78.383 | 1.00 | 45.80 | B | C |
| ATOM | 3718 | CD | GLU | B | 561 | 43.015 | 46.594 | 78.209 | 1.00 | 53.50 | B | C |
| ATOM | 3719 | OE1 | GLU | B | 561 | 44.120 | 46.072 | 77.939 | 1.00 | 57.21 | B | O |
| ATOM | 3720 | OE2 | GLU | B | 561 | 41.963 | 45.929 | 78.338 | 1.00 | 56.06 | B | O |
| ATOM | 3721 | C | GLU | B | 561 | 45.288 | 50.833 | 77.316 | 1.00 | 32.44 | B | C |
| ATOM | 3722 | O | GLU | B | 561 | 46.116 | 50.852 | 78.223 | 1.00 | 37.16 | B | O |
| ATOM | 3723 | N | ARG | B | 562 | 45.574 | 51.228 | 76.077 | 1.00 | 28.99 | B | N |
| ATOM | 3724 | CA | ARG | B | 562 | 46.905 | 51.720 | 75.733 | 1.00 | 26.01 | B | C |
| ATOM | 3725 | CB | ARG | B | 562 | 47.178 | 51.525 | 74.237 | 1.00 | 24.04 | B | C |
| ATOM | 3726 | CG | ARG | B | 562 | 46.985 | 50.091 | 73.743 | 1.00 | 24.32 | B | C |
| ATOM | 3727 | CD | ARG | B | 562 | 48.108 | 49.652 | 72.807 | 1.00 | 25.33 | B | C |
| ATOM | 3728 | NE | ARG | B | 562 | 49.430 | 49.840 | 73.403 | 1.00 | 27.03 | B | N |
| ATOM | 3729 | CZ | ARG | B | 562 | 50.578 | 49.781 | 72.735 | 1.00 | 28.27 | B | C |
| ATOM | 3730 | NH1 | ARG | B | 562 | 50.589 | 49.539 | 71.433 | 1.00 | 30.18 | B | N |
| ATOM | 3731 | NH2 | ARG | B | 562 | 51.722 | 49.975 | 73.371 | 1.00 | 32.38 | B | N |
| ATOM | 3732 | C | ARG | B | 562 | 47.035 | 53.196 | 76.091 | 1.00 | 27.63 | B | C |
| ATOM | 3733 | O | ARG | B | 562 | 48.092 | 53.798 | 75.916 | 1.00 | 28.05 | B | O |
| ATOM | 3734 | N | GLY | B | 563 | 45.957 | 53.778 | 76.608 | 1.00 | 26.65 | B | N |
| ATOM | 3735 | CA | GLY | B | 563 | 45.988 | 55.184 | 76.955 | 1.00 | 25.39 | B | C |
| ATOM | 3736 | C | GLY | B | 563 | 45.908 | 56.039 | 75.702 | 1.00 | 26.93 | B | C |
| ATOM | 3737 | O | GLY | B | 563 | 46.378 | 57.186 | 75.680 | 1.00 | 27.01 | B | O |
| ATOM | 3738 | N | MET | B | 564 | 45.308 | 55.477 | 74.652 | 1.00 | 26.61 | B | N |
| ATOM | 3739 | CA | MET | B | 564 | 45.154 | 56.175 | 73.377 | 1.00 | 24.20 | B | C |
| ATOM | 3740 | CB | MET | B | 564 | 45.471 | 55.235 | 72.214 | 1.00 | 23.14 | B | C |
| ATOM | 3741 | CG | MET | B | 564 | 46.943 | 55.130 | 71.862 | 1.00 | 25.89 | B | C |
| ATOM | 3742 | SD | MET | B | 564 | 47.284 | 53.634 | 70.912 | 1.00 | 24.82 | B | S |
| ATOM | 3743 | CE | MET | B | 564 | 48.865 | 54.024 | 70.244 | 1.00 | 24.91 | B | C |
| ATOM | 3744 | C | MET | B | 564 | 43.727 | 56.681 | 73.236 | 1.00 | 23.51 | B | C |
| ATOM | 3745 | O | MET | B | 564 | 42.831 | 56.225 | 73.943 | 1.00 | 25.15 | B | O |
| ATOM | 3746 | N | ASN | B | 565 | 43.523 | 57.616 | 72.313 | 1.00 | 23.00 | B | N |
| ATOM | 3747 | CA | ASN | B | 565 | 42.207 | 58.203 | 72.069 | 1.00 | 21.30 | B | C |
| ATOM | 3748 | CB | ASN | B | 565 | 42.340 | 59.430 | 71.152 | 1.00 | 22.09 | B | C |
| ATOM | 3749 | CG | ASN | B | 565 | 42.976 | 59.098 | 69.803 | 1.00 | 22.65 | B | C |
| ATOM | 3750 | OD1 | ASN | B | 565 | 44.084 | 58.555 | 69.736 | 1.00 | 24.04 | B | O |
| ATOM | 3751 | ND2 | ASN | B | 565 | 42.276 | 59.429 | 68.724 | 1.00 | 18.67 | B | N |
| ATOM | 3752 | C | ASN | B | 565 | 41.236 | 57.199 | 71.451 | 1.00 | 20.53 | B | C |
| ATOM | 3753 | O | ASN | B | 565 | 41.653 | 56.276 | 70.754 | 1.00 | 20.58 | B | O |
| ATOM | 3754 | N | THR | B | 566 | 39.943 | 57.381 | 71.718 | 1.00 | 18.63 | B | N |
| ATOM | 3755 | CA | THR | B | 566 | 38.906 | 56.502 | 71.189 | 1.00 | 16.48 | B | C |
| ATOM | 3756 | CB | THR | B | 566 | 37.963 | 56.011 | 72.306 | 1.00 | 14.84 | B | C |
| ATOM | 3757 | OG1 | THR | B | 566 | 37.668 | 57.093 | 73.195 | 1.00 | 17.79 | B | O |
| ATOM | 3758 | CG2 | THR | B | 566 | 38.609 | 54.885 | 73.083 | 1.00 | 14.41 | B | C |
| ATOM | 3759 | C | THR | B | 566 | 38.092 | 57.261 | 70.139 | 1.00 | 14.16 | B | C |
| ATOM | 3760 | O | THR | B | 566 | 38.233 | 58.470 | 70.011 | 1.00 | 16.37 | B | O |
| ATOM | 3761 | N | PHE | B | 567 | 37.246 | 56.552 | 69.394 | 1.00 | 12.07 | B | N |
| ATOM | 3762 | CA | PHE | B | 567 | 36.435 | 57.168 | 68.339 | 1.00 | 12.54 | B | C |
| ATOM | 3763 | CB | PHE | B | 567 | 36.792 | 56.583 | 66.965 | 1.00 | 10.57 | B | C |
| ATOM | 3764 | CG | PHE | B | 567 | 38.257 | 56.364 | 66.756 | 1.00 | 9.81 | B | C |
| ATOM | 3765 | CD1 | PHE | B | 567 | 39.097 | 57.429 | 66.461 | 1.00 | 6.57 | B | C |
| ATOM | 3766 | CD2 | PHE | B | 567 | 38.801 | 55.089 | 66.863 | 1.00 | 10.41 | B | C |
| ATOM | 3767 | CE1 | PHE | B | 567 | 40.462 | 57.231 | 66.276 | 1.00 | 7.34 | B | C |
| ATOM | 3768 | CE2 | PHE | B | 567 | 40.172 | 54.885 | 66.681 | 1.00 | 11.95 | B | C |
| ATOM | 3769 | CZ | PHE | B | 567 | 41.001 | 55.962 | 66.386 | 1.00 | 3.35 | B | C |
| ATOM | 3770 | C | PHE | B | 567 | 34.941 | 56.974 | 68.540 | 1.00 | 12.78 | B | C |
| ATOM | 3771 | O | PHE | B | 567 | 34.511 | 55.987 | 69.137 | 1.00 | 12.93 | B | O |
| ATOM | 3772 | N | LEU | B | 568 | 34.157 | 57.914 | 68.023 | 1.00 | 12.12 | B | N |
| ATOM | 3773 | CA | LEU | B | 568 | 32.705 | 57.839 | 68.123 | 1.00 | 12.63 | B | C |
| ATOM | 3774 | CB | LEU | B | 568 | 32.103 | 59.200 | 68.485 | 1.00 | 11.77 | B | C |
| ATOM | 3775 | CG | LEU | B | 568 | 32.652 | 60.015 | 69.658 | 1.00 | 10.91 | B | C |
| ATOM | 3776 | CD1 | LEU | B | 568 | 31.911 | 61.336 | 69.716 | 1.00 | 7.13 | B | C |
| ATOM | 3777 | CD2 | LEU | B | 568 | 32.481 | 59.263 | 70.962 | 1.00 | 9.16 | B | C |
| ATOM | 3778 | C | LEU | B | 568 | 32.163 | 57.425 | 66.768 | 1.00 | 12.66 | B | C |
| ATOM | 3779 | O | LEU | B | 568 | 32.828 | 57.597 | 65.751 | 1.00 | 13.06 | B | O |
| ATOM | 3780 | N | PHE | B | 569 | 30.949 | 56.885 | 66.764 | 1.00 | 13.61 | B | N |
| ATOM | 3781 | CA | PHE | B | 569 | 30.279 | 56.456 | 65.539 | 1.00 | 14.13 | B | C |
| ATOM | 3782 | CB | PHE | B | 569 | 29.783 | 55.010 | 65.706 | 1.00 | 15.11 | B | C |
| ATOM | 3783 | CG | PHE | B | 569 | 29.129 | 54.422 | 64.477 | 1.00 | 11.99 | B | C |
| ATOM | 3784 | CD1 | PHE | B | 569 | 29.691 | 54.583 | 63.217 | 1.00 | 12.63 | B | C |
| ATOM | 3785 | CD2 | PHE | B | 569 | 27.944 | 53.695 | 64.591 | 1.00 | 10.91 | B | C |
| ATOM | 3786 | CE1 | PHE | B | 569 | 29.075 | 54.026 | 62.082 | 1.00 | 15.04 | B | C |
| ATOM | 3787 | CE2 | PHE | B | 569 | 27.324 | 53.139 | 63.471 | 1.00 | 11.12 | B | C |
| ATOM | 3788 | CZ | PHE | B | 569 | 27.890 | 53.303 | 62.216 | 1.00 | 12.17 | B | C |
| ATOM | 3789 | C | PHE | B | 569 | 29.108 | 57.424 | 65.335 | 1.00 | 16.39 | B | C |
| ATOM | 3790 | O | PHE | B | 569 | 28.132 | 57.396 | 66.084 | 1.00 | 16.15 | B | O |
| ATOM | 3791 | N | ARG | B | 570 | 29.226 | 58.290 | 64.328 | 1.00 | 17.94 | B | N |
| ATOM | 3792 | CA | ARG | B | 570 | 28.206 | 59.296 | 64.006 | 1.00 | 16.06 | B | C |
| ATOM | 3793 | CB | ARG | B | 570 | 28.776 | 60.697 | 64.268 | 1.00 | 14.01 | B | C |
| ATOM | 3794 | CG | ARG | B | 570 | 29.535 | 60.818 | 65.585 | 1.00 | 12.35 | B | C |
| ATOM | 3795 | CD | ARG | B | 570 | 30.416 | 62.057 | 65.645 | 1.00 | 12.00 | B | C |
| ATOM | 3796 | NE | ARG | B | 570 | 29.720 | 63.281 | 65.250 | 1.00 | 8.77 | B | N |
| ATOM | 3797 | CZ | ARG | B | 570 | 30.286 | 64.486 | 65.241 | 1.00 | 9.76 | B | C |
| ATOM | 3798 | NH1 | ARG | B | 570 | 31.555 | 64.637 | 65.608 | 1.00 | 10.20 | B | N |
| ATOM | 3799 | NH2 | ARG | B | 570 | 29.592 | 65.542 | 64.841 | 1.00 | 7.87 | B | N |
| ATOM | 3800 | C | ARG | B | 570 | 27.803 | 59.173 | 62.538 | 1.00 | 14.45 | B | C |
| ATOM | 3801 | O | ARG | B | 570 | 28.226 | 59.967 | 61.701 | 1.00 | 16.65 | B | O |
| ATOM | 3802 | N | PRO | B | 571 | 26.944 | 58.201 | 62.209 | 1.00 | 13.71 | B | N |
| ATOM | 3803 | CD | PRO | B | 571 | 26.285 | 57.235 | 63.106 | 1.00 | 12.57 | B | C |
| ATOM | 3804 | CA | PRO | B | 571 | 26.523 | 58.009 | 60.817 | 1.00 | 12.77 | B | C |
| ATOM | 3805 | CB | PRO | B | 571 | 26.076 | 56.557 | 60.792 | 1.00 | 9.84 | B | C |
| ATOM | 3806 | CG | PRO | B | 571 | 25.461 | 56.379 | 62.146 | 1.00 | 12.27 | B | C |
| ATOM | 3807 | C | PRO | B | 571 | 25.415 | 58.924 | 60.311 | 1.00 | 15.07 | B | C |
| ATOM | 3808 | O | PRO | B | 571 | 24.749 | 59.617 | 61.088 | 1.00 | 12.63 | B | O |
| ATOM | 3809 | N | HIS | B | 572 | 25.243 | 58.926 | 58.989 | 1.00 | 13.72 | B | N |
| ATOM | 3810 | CA | HIS | B | 572 | 24.181 | 59.690 | 58.360 | 1.00 | 13.68 | B | C |
| ATOM | 3811 | CB | HIS | B | 572 | 24.387 | 59.774 | 56.849 | 1.00 | 14.88 | B | C |
| ATOM | 3812 | CG | HIS | B | 572 | 25.239 | 60.922 | 56.413 | 1.00 | 12.47 | B | C |
| ATOM | 3813 | CD2 | HIS | B | 572 | 25.070 | 61.828 | 55.420 | 1.00 | 12.06 | B | C |
| ATOM | 3814 | ND1 | HIS | B | 572 | 26.448 | 61.222 | 57.008 | 1.00 | 10.08 | B | N |
| ATOM | 3815 | CE1 | HIS | B | 572 | 26.985 | 62.264 | 56.400 | 1.00 | 13.82 | B | C |
| ATOM | 3816 | NE2 | HIS | B | 572 | 26.168 | 62.651 | 55.431 | 1.00 | 15.15 | B | N |
| ATOM | 3817 | C | HIS | B | 572 | 23.012 | 58.768 | 58.650 | 1.00 | 13.11 | B | C |
| ATOM | 3818 | O | HIS | B | 572 | 23.152 | 57.555 | 58.516 | 1.00 | 12.49 | B | O |
| ATOM | 3819 | N | CYS | B | 573 | 21.871 | 59.316 | 59.055 | 1.00 | 12.08 | B | N |
| ATOM | 3820 | CA | CYS | B | 573 | 20.739 | 58.459 | 59.366 | 1.00 | 12.50 | B | C |
| ATOM | 3821 | CB | CYS | B | 573 | 20.914 | 57.857 | 60.768 | 1.00 | 11.12 | B | C |
| ATOM | 3822 | SG | CYS | B | 573 | 19.701 | 56.585 | 61.228 | 1.00 | 18.20 | B | S |
| ATOM | 3823 | C | CYS | B | 573 | 19.425 | 59.210 | 59.290 | 1.00 | 12.53 | B | C |
| ATOM | 3824 | O | CYS | B | 573 | 19.326 | 60.363 | 59.714 | 1.00 | 10.82 | B | O |
| ATOM | 3825 | N | GLY | B | 574 | 18.423 | 58.548 | 58.724 | 1.00 | 12.14 | B | N |
| ATOM | 3826 | CA | GLY | B | 574 | 17.105 | 59.143 | 58.610 | 1.00 | 13.87 | B | C |
| ATOM | 3827 | C | GLY | B | 574 | 16.888 | 60.177 | 57.527 | 1.00 | 15.39 | B | C |
| ATOM | 3828 | O | GLY | B | 574 | 15.848 | 60.836 | 57.519 | 1.00 | 17.25 | B | O |
| ATOM | 3829 | N | GLU | B | 575 | 17.850 | 60.355 | 56.626 | 1.00 | 15.55 | B | N |
| ATOM | 3830 | CA | GLU | B | 575 | 17.667 | 61.323 | 55.549 | 1.00 | 14.55 | B | C |
| ATOM | 3831 | CB | GLU | B | 575 | 18.940 | 61.474 | 54.723 | 1.00 | 15.22 | B | C |
| ATOM | 3832 | CG | GLU | B | 575 | 18.835 | 62.542 | 53.649 | 1.00 | 17.86 | B | C |
| ATOM | 3833 | CD | GLU | B | 575 | 20.136 | 62.725 | 52.895 | 1.00 | 20.91 | B | C |
| ATOM | 3834 | OE1 | GLU | B | 575 | 20.390 | 63.843 | 52.391 | 1.00 | 23.60 | B | O |
| ATOM | 3835 | OE2 | GLU | B | 575 | 20.910 | 61.748 | 52.809 | 1.00 | 18.97 | B | O |
| ATOM | 3836 | C | GLU | B | 575 | 16.564 | 60.773 | 54.668 | 1.00 | 16.70 | B | C |
| ATOM | 3837 | O | GLU | B | 575 | 15.809 | 61.525 | 54.062 | 1.00 | 17.63 | B | O |
| ATOM | 3838 | N | VAL | B | 576 | 16.500 | 59.445 | 54.605 | 1.00 | 16.96 | B | N |
| ATOM | 3839 | CA | VAL | B | 576 | 15.500 | 58.719 | 53.836 | 1.00 | 20.90 | B | C |
| ATOM | 3840 | CB | VAL | B | 576 | 15.602 | 58.986 | 52.328 | 1.00 | 24.67 | B | C |
| ATOM | 3841 | CG1 | VAL | B | 576 | 14.697 | 60.165 | 51.947 | 1.00 | 33.46 | B | C |
| ATOM | 3842 | CG2 | VAL | B | 576 | 17.039 | 59.247 | 51.941 | 1.00 | 28.82 | B | C |
| ATOM | 3843 | C | VAL | B | 576 | 15.690 | 57.232 | 54.057 | 1.00 | 21.32 | B | C |
| ATOM | 3844 | O | VAL | B | 576 | 16.607 | 56.817 | 54.761 | 1.00 | 23.89 | B | O |
| ATOM | 3845 | N | GLY | B | 577 | 14.823 | 56.430 | 53.451 | 1.00 | 20.23 | B | N |
| ATOM | 3846 | CA | GLY | B | 577 | 14.921 | 54.995 | 53.614 | 1.00 | 17.38 | B | C |
| ATOM | 3847 | C | GLY | B | 577 | 13.943 | 54.533 | 54.672 | 1.00 | 19.11 | B | C |
| ATOM | 3848 | O | GLY | B | 577 | 13.025 | 55.264 | 55.032 | 1.00 | 16.11 | B | O |
| ATOM | 3849 | N | ALA | B | 578 | 14.147 | 53.321 | 55.174 | 1.00 | 18.93 | B | N |
| ATOM | 3850 | CA | ALA | B | 578 | 13.280 | 52.752 | 56.195 | 1.00 | 21.02 | B | C |
| ATOM | 3851 | CB | ALA | B | 578 | 13.462 | 51.241 | 56.228 | 1.00 | 18.20 | B | C |
| ATOM | 3852 | C | ALA | B | 578 | 13.540 | 53.342 | 57.581 | 1.00 | 22.14 | B | C |
| ATOM | 3853 | O | ALA | B | 578 | 14.634 | 53.824 | 57.866 | 1.00 | 21.78 | B | O |
| ATOM | 3854 | N | LEU | B | 579 | 12.528 | 53.292 | 58.442 | 1.00 | 23.91 | B | N |
| ATOM | 3855 | CA | LEU | B | 579 | 12.653 | 53.812 | 59.805 | 1.00 | 26.36 | B | C |
| ATOM | 3856 | CB | LEU | B | 579 | 11.307 | 53.741 | 60.534 | 1.00 | 25.79 | B | C |
| ATOM | 3857 | CG | LEU | B | 579 | 10.350 | 54.917 | 60.346 | 1.00 | 26.00 | B | C |
| ATOM | 3858 | CD1 | LEU | B | 579 | 8.961 | 54.508 | 60.806 | 1.00 | 26.62 | B | C |
| ATOM | 3859 | CD2 | LEU | B | 579 | 10.850 | 56.119 | 61.130 | 1.00 | 26.99 | B | C |
| ATOM | 3860 | C | LEU | B | 579 | 13.681 | 53.004 | 60.588 | 1.00 | 25.77 | B | C |
| ATOM | 3861 | O | LEU | B | 579 | 14.369 | 53.534 | 61.464 | 1.00 | 27.11 | B | O |
| ATOM | 3862 | N | THR | B | 580 | 13.784 | 51.719 | 60.261 | 1.00 | 22.64 | B | N |
| ATOM | 3863 | CA | THR | B | 580 | 14.719 | 50.837 | 60.944 | 1.00 | 23.86 | B | C |
| ATOM | 3864 | CB | THR | B | 580 | 14.779 | 49.441 | 60.278 | 1.00 | 25.29 | B | C |
| ATOM | 3865 | OG1 | THR | B | 580 | 15.496 | 49.525 | 59.040 | 1.00 | 34.37 | B | O |
| ATOM | 3866 | CG2 | THR | B | 580 | 13.383 | 48.918 | 60.007 | 1.00 | 25.91 | B | C |
| ATOM | 3867 | C | THR | B | 580 | 16.130 | 51.397 | 61.017 | 1.00 | 20.98 | B | C |
| ATOM | 3868 | O | THR | B | 580 | 16.946 | 50.908 | 61.788 | 1.00 | 23.94 | B | O |
| ATOM | 3869 | N | HIS | B | 581 | 16.421 | 52.421 | 60.220 | 1.00 | 21.10 | B | N |
| ATOM | 3870 | CA | HIS | B | 581 | 17.752 | 53.033 | 60.218 | 1.00 | 17.71 | B | C |
| ATOM | 3871 | CB | HIS | B | 581 | 17.930 | 53.975 | 59.019 | 1.00 | 16.67 | B | C |
| ATOM | 3872 | CG | HIS | B | 581 | 17.896 | 53.292 | 57.692 | 1.00 | 14.88 | B | C |
| ATOM | 3873 | CD2 | HIS | B | 581 | 17.513 | 52.043 | 57.337 | 1.00 | 15.90 | B | C |
| ATOM | 3874 | ND1 | HIS | B | 581 | 18.278 | 53.919 | 56.529 | 1.00 | 18.27 | B | N |
| ATOM | 3875 | CE1 | HIS | B | 581 | 18.132 | 53.089 | 55.513 | 1.00 | 18.05 | B | C |
| ATOM | 3876 | NE2 | HIS | B | 581 | 17.669 | 51.943 | 55.976 | 1.00 | 16.96 | B | N |
| ATOM | 3877 | C | HIS | B | 581 | 17.955 | 53.841 | 61.489 | 1.00 | 18.09 | B | C |
| ATOM | 3878 | O | HIS | B | 581 | 19.049 | 53.863 | 62.051 | 1.00 | 19.06 | B | O |
| ATOM | 3879 | N | LEU | B | 582 | 16.898 | 54.519 | 61.930 | 1.00 | 16.23 | B | N |
| ATOM | 3880 | CA | LEU | B | 582 | 16.972 | 55.348 | 63.127 | 1.00 | 15.61 | B | C |
| ATOM | 3881 | CB | LEU | B | 582 | 15.788 | 56.311 | 63.163 | 1.00 | 12.21 | B | C |
| ATOM | 3882 | CG | LEU | B | 582 | 15.908 | 57.402 | 62.094 | 1.00 | 12.31 | B | C |
| ATOM | 3883 | CD1 | LEU | B | 582 | 14.535 | 57.865 | 61.686 | 1.00 | 12.00 | B | C |
| ATOM | 3884 | CD2 | LEU | B | 582 | 16.741 | 58.566 | 62.622 | 1.00 | 8.84 | B | C |
| ATOM | 3885 | C | LEU | B | 582 | 16.991 | 54.478 | 64.372 | 1.00 | 16.10 | B | C |
| ATOM | 3886 | O | LEU | B | 582 | 17.597 | 54.820 | 65.383 | 1.00 | 15.14 | B | O |
| ATOM | 3887 | N | MET | B | 583 | 16.326 | 53.338 | 64.278 | 1.00 | 17.87 | B | N |
| ATOM | 3888 | CA | MET | B | 583 | 16.266 | 52.399 | 65.375 | 1.00 | 18.05 | B | C |
| ATOM | 3889 | CB | MET | B | 583 | 15.279 | 51.285 | 65.030 | 1.00 | 20.16 | B | C |
| ATOM | 3890 | CG | MET | B | 583 | 15.176 | 50.201 | 66.077 | 1.00 | 26.64 | B | C |
| ATOM | 3891 | SD | MET | B | 583 | 15.626 | 48.591 | 65.416 | 1.00 | 37.55 | B | S |
| ATOM | 3892 | CE | MET | B | 583 | 17.356 | 48.531 | 65.860 | 1.00 | 36.29 | B | C |
| ATOM | 3893 | C | MET | B | 583 | 17.657 | 51.825 | 65.624 | 1.00 | 15.75 | B | C |
| ATOM | 3894 | O | MET | B | 583 | 18.116 | 51.763 | 66.757 | 1.00 | 16.68 | B | O |
| ATOM | 3895 | N | THR | B | 584 | 18.330 | 51.419 | 64.554 | 1.00 | 14.69 | B | N |
| ATOM | 3896 | CA | THR | B | 584 | 19.670 | 50.847 | 64.650 | 1.00 | 11.48 | B | C |
| ATOM | 3897 | CB | THR | B | 584 | 20.112 | 50.293 | 63.270 | 1.00 | 12.21 | B | C |
| ATOM | 3898 | OG1 | THR | B | 584 | 19.438 | 49.058 | 63.018 | 1.00 | 10.87 | B | O |
| ATOM | 3899 | CG2 | THR | B | 584 | 21.611 | 50.049 | 63.223 | 1.00 | 11.68 | B | C |
| ATOM | 3900 | C | THR | B | 584 | 20.687 | 51.879 | 65.156 | 1.00 | 12.12 | B | C |
| ATOM | 3901 | O | THR | B | 584 | 21.663 | 51.531 | 65.825 | 1.00 | 11.76 | B | O |
| ATOM | 3902 | N | ALA | B | 585 | 20.458 | 53.150 | 64.833 | 1.00 | 11.70 | B | N |
| ATOM | 3903 | CA | ALA | B | 585 | 21.351 | 54.217 | 65.268 | 1.00 | 8.50 | B | C |
| ATOM | 3904 | CB | ALA | B | 585 | 21.134 | 55.471 | 64.429 | 1.00 | 6.65 | B | C |
| ATOM | 3905 | C | ALA | B | 585 | 21.088 | 54.511 | 66.739 | 1.00 | 9.30 | B | C |
| ATOM | 3906 | O | ALA | B | 585 | 21.974 | 54.958 | 67.456 | 1.00 | 9.75 | B | O |
| ATOM | 3907 | N | PHE | B | 586 | 19.865 | 54.260 | 67.190 | 1.00 | 11.28 | B | N |
| ATOM | 3908 | CA | PHE | B | 586 | 19.525 | 54.480 | 68.590 | 1.00 | 13.96 | B | C |
| ATOM | 3909 | CB | PHE | B | 586 | 18.033 | 54.215 | 68.829 | 1.00 | 12.96 | B | C |
| ATOM | 3910 | CG | PHE | B | 586 | 17.633 | 54.218 | 70.288 | 1.00 | 16.07 | B | C |
| ATOM | 3911 | CD1 | PHE | B | 586 | 17.399 | 55.414 | 70.960 | 1.00 | 12.74 | B | C |
| ATOM | 3912 | CD2 | PHE | B | 586 | 17.497 | 53.018 | 70.993 | 1.00 | 14.04 | B | C |
| ATOM | 3913 | CE1 | PHE | B | 586 | 17.040 | 55.413 | 72.306 | 1.00 | 11.61 | B | C |
| ATOM | 3914 | CE2 | PHE | B | 586 | 17.137 | 53.009 | 72.340 | 1.00 | 11.09 | B | C |
| ATOM | 3915 | CZ | PHE | B | 586 | 16.908 | 54.206 | 72.996 | 1.00 | 12.94 | B | C |
| ATOM | 3916 | C | PHE | B | 586 | 20.373 | 53.523 | 69.437 | 1.00 | 16.59 | B | C |
| ATOM | 3917 | O | PHE | B | 586 | 20.728 | 53.839 | 70.579 | 1.00 | 15.18 | B | O |
| ATOM | 3918 | N | MET | B | 587 | 20.701 | 52.367 | 68.856 | 1.00 | 14.97 | B | N |
| ATOM | 3919 | CA | MET | B | 587 | 21.505 | 51.340 | 69.519 | 1.00 | 16.05 | B | C |
| ATOM | 3920 | CB | MET | B | 587 | 21.173 | 49.942 | 68.970 | 1.00 | 11.83 | B | C |
| ATOM | 3921 | CG | MET | B | 587 | 19.740 | 49.483 | 69.099 | 1.00 | 15.20 | B | C |
| ATOM | 3922 | SD | MET | B | 587 | 19.514 | 47.801 | 68.442 | 1.00 | 20.51 | B | S |
| ATOM | 3923 | CE | MET | B | 587 | 20.743 | 46.876 | 69.421 | 1.00 | 13.68 | B | C |
| ATOM | 3924 | C | MET | B | 587 | 23.019 | 51.503 | 69.366 | 1.00 | 16.84 | B | C |
| ATOM | 3925 | O | MET | B | 587 | 23.773 | 51.159 | 70.278 | 1.00 | 22.61 | B | O |
| ATOM | 3926 | N | THR | B | 588 | 23.462 | 52.028 | 68.224 | 1.00 | 13.80 | B | N |
| ATOM | 3927 | CA | THR | B | 588 | 24.894 | 52.112 | 67.933 | 1.00 | 12.75 | B | C |
| ATOM | 3928 | CB | THR | B | 588 | 25.197 | 51.340 | 66.637 | 1.00 | 12.97 | B | C |
| ATOM | 3929 | OG1 | THR | B | 588 | 24.428 | 51.911 | 65.572 | 1.00 | 16.10 | B | O |
| ATOM | 3930 | CG2 | THR | B | 588 | 24.819 | 49.865 | 66.770 | 1.00 | 8.95 | B | C |
| ATOM | 3931 | C | THR | B | 588 | 25.619 | 53.442 | 67.790 | 1.00 | 11.89 | B | C |
| ATOM | 3932 | O | THR | B | 588 | 26.856 | 53.474 | 67.836 | 1.00 | 11.92 | B | O |
| ATOM | 3933 | N | ALA | B | 589 | 24.895 | 54.539 | 67.616 | 1.00 | 11.12 | B | N |
| ATOM | 3934 | CA | ALA | B | 589 | 25.582 | 55.809 | 67.403 | 1.00 | 11.41 | B | C |
| ATOM | 3935 | CB | ALA | B | 589 | 25.077 | 56.426 | 66.108 | 1.00 | 11.17 | B | C |
| ATOM | 3936 | C | ALA | B | 589 | 25.544 | 56.850 | 68.512 | 1.00 | 9.92 | B | C |
| ATOM | 3937 | O | ALA | B | 589 | 24.531 | 57.030 | 69.184 | 1.00 | 12.36 | B | O |
| ATOM | 3938 | N | ASP | B | 590 | 26.661 | 57.542 | 68.688 | 1.00 | 11.28 | B | N |
| ATOM | 3939 | CA | ASP | B | 590 | 26.761 | 58.596 | 69.687 | 1.00 | 14.59 | B | C |
| ATOM | 3940 | CB | ASP | B | 590 | 28.191 | 59.145 | 69.727 | 1.00 | 15.55 | B | C |
| ATOM | 3941 | CG | ASP | B | 590 | 28.390 | 60.190 | 70.816 | 1.00 | 19.19 | B | C |
| ATOM | 3942 | OD1 | ASP | B | 590 | 28.061 | 61.366 | 70.569 | 1.00 | 22.65 | B | O |
| ATOM | 3943 | OD2 | ASP | B | 590 | 28.876 | 59.844 | 71.918 | 1.00 | 18.92 | B | O |
| ATOM | 3944 | C | ASP | B | 590 | 25.768 | 59.691 | 69.273 | 1.00 | 17.70 | B | C |
| ATOM | 3945 | O | ASP | B | 590 | 24.986 | 60.187 | 70.088 | 1.00 | 18.25 | B | O |
| ATOM | 3946 | N | ASN | B | 591 | 25.813 | 60.060 | 67.994 | 1.00 | 19.19 | B | N |
| ATOM | 3947 | CA | ASN | B | 591 | 24.906 | 61.055 | 67.418 | 1.00 | 15.76 | B | C |
| ATOM | 3948 | CB | ASN | B | 591 | 25.369 | 62.486 | 67.748 | 1.00 | 14.89 | B | C |
| ATOM | 3949 | CG | ASN | B | 591 | 26.684 | 62.850 | 67.111 | 1.00 | 12.98 | B | C |
| ATOM | 3950 | OD1 | ASN | B | 591 | 27.734 | 62.812 | 67.750 | 1.00 | 15.41 | B | O |
| ATOM | 3951 | ND2 | ASN | B | 591 | 26.636 | 63.227 | 65.849 | 1.00 | 15.45 | B | N |
| ATOM | 3952 | C | ASN | B | 591 | 24.813 | 60.815 | 65.906 | 1.00 | 14.64 | B | C |
| ATOM | 3953 | O | ASN | B | 591 | 25.583 | 60.030 | 65.355 | 1.00 | 13.91 | B | O |
| ATOM | 3954 | N | ILE | B | 592 | 23.856 | 61.462 | 65.244 | 1.00 | 13.85 | B | N |
| ATOM | 3955 | CA | ILE | B | 592 | 23.648 | 61.280 | 63.805 | 1.00 | 12.58 | B | C |
| ATOM | 3956 | CB | ILE | B | 592 | 22.323 | 60.522 | 63.518 | 1.00 | 11.83 | B | C |
| ATOM | 3957 | CG2 | ILE | B | 592 | 22.308 | 59.167 | 64.209 | 1.00 | 11.08 | B | C |
| ATOM | 3958 | CG1 | ILE | B | 592 | 21.143 | 61.372 | 63.997 | 1.00 | 7.11 | B | C |
| ATOM | 3959 | CD1 | ILE | B | 592 | 19.791 | 60.873 | 63.534 | 1.00 | 5.09 | B | C |
| ATOM | 3960 | C | ILE | B | 592 | 23.556 | 62.594 | 63.030 | 1.00 | 13.15 | B | C |
| ATOM | 3961 | O | ILE | B | 592 | 23.615 | 63.684 | 63.604 | 1.00 | 12.68 | B | O |
| ATOM | 3962 | N | SER | B | 593 | 23.403 | 62.457 | 61.714 | 1.00 | 13.61 | B | N |
| ATOM | 3963 | CA | SER | B | 593 | 23.236 | 63.580 | 60.798 | 1.00 | 9.79 | B | C |
| ATOM | 3964 | CB | SER | B | 593 | 24.340 | 63.597 | 59.752 | 1.00 | 12.13 | B | C |
| ATOM | 3965 | OG | SER | B | 593 | 25.594 | 63.887 | 60.331 | 1.00 | 13.84 | B | O |
| ATOM | 3966 | C | SER | B | 593 | 21.900 | 63.368 | 60.095 | 1.00 | 8.61 | B | C |
| ATOM | 3967 | O | SER | B | 593 | 21.535 | 62.231 | 59.783 | 1.00 | 8.68 | B | O |
| ATOM | 3968 | N | HIS | B | 594 | 21.184 | 64.468 | 59.859 | 1.00 | 11.92 | B | N |
| ATOM | 3969 | CA | HIS | B | 594 | 19.868 | 64.482 | 59.190 | 1.00 | 13.39 | B | C |
| ATOM | 3970 | CB | HIS | B | 594 | 19.843 | 63.527 | 57.980 | 1.00 | 11.97 | B | C |
| ATOM | 3971 | CG | HIS | B | 594 | 20.721 | 63.968 | 56.849 | 1.00 | 13.33 | B | C |
| ATOM | 3972 | CD2 | HIS | B | 594 | 21.725 | 63.329 | 56.197 | 1.00 | 11.54 | B | C |
| ATOM | 3973 | ND1 | HIS | B | 594 | 20.657 | 65.236 | 56.304 | 1.00 | 14.19 | B | N |
| ATOM | 3974 | CE1 | HIS | B | 594 | 21.584 | 65.360 | 55.369 | 1.00 | 10.96 | B | C |
| ATOM | 3975 | NE2 | HIS | B | 594 | 22.244 | 64.218 | 55.284 | 1.00 | 13.35 | B | N |
| ATOM | 3976 | C | HIS | B | 594 | 18.721 | 64.152 | 60.141 | 1.00 | 11.34 | B | C |
| ATOM | 3977 | O | HIS | B | 594 | 18.101 | 65.047 | 60.693 | 1.00 | 14.39 | B | O |
| ATOM | 3978 | N | GLY | B | 595 | 18.430 | 62.874 | 60.324 | 1.00 | 11.33 | B | N |
| ATOM | 3979 | CA | GLY | B | 595 | 17.359 | 62.489 | 61.228 | 1.00 | 13.02 | B | C |
| ATOM | 3980 | C | GLY | B | 595 | 15.942 | 62.920 | 60.870 | 1.00 | 14.52 | B | C |
| ATOM | 3981 | O | GLY | B | 595 | 15.054 | 62.907 | 61.725 | 1.00 | 15.68 | B | O |
| ATOM | 3982 | N | LEU | B | 596 | 15.709 | 63.264 | 59.609 | 1.00 | 15.23 | B | N |
| ATOM | 3983 | CA | LEU | B | 596 | 14.390 | 63.714 | 59.164 | 1.00 | 13.65 | B | C |
| ATOM | 3984 | CB | LEU | B | 596 | 14.415 | 64.020 | 57.666 | 1.00 | 12.35 | B | C |
| ATOM | 3985 | CG | LEU | B | 596 | 15.376 | 65.114 | 57.217 | 1.00 | 11.44 | B | C |
| ATOM | 3986 | CD1 | LEU | B | 596 | 15.335 | 65.239 | 55.696 | 1.00 | 6.72 | B | C |
| ATOM | 3987 | CD2 | LEU | B | 596 | 14.995 | 66.420 | 57.899 | 1.00 | 9.19 | B | C |
| ATOM | 3988 | C | LEU | B | 596 | 13.251 | 62.746 | 59.435 | 1.00 | 13.16 | B | C |
| ATOM | 3989 | O | LEU | B | 596 | 12.165 | 63.149 | 59.862 | 1.00 | 14.03 | B | O |
| ATOM | 3990 | N | ASN | B | 597 | 13.495 | 61.471 | 59.172 | 1.00 | 13.15 | B | N |
| ATOM | 3991 | CA | ASN | B | 597 | 12.471 | 60.460 | 59.352 | 1.00 | 13.55 | B | C |
| ATOM | 3992 | CB | ASN | B | 597 | 12.940 | 59.143 | 58.725 | 1.00 | 14.59 | B | C |
| ATOM | 3993 | CG | ASN | B | 597 | 12.728 | 59.115 | 57.216 | 1.00 | 14.64 | B | C |
| ATOM | 3994 | OD1 | ASN | B | 597 | 12.048 | 59.978 | 56.657 | 1.00 | 15.09 | B | O |
| ATOM | 3995 | ND2 | ASN | B | 597 | 13.309 | 58.126 | 56.553 | 1.00 | 15.09 | B | N |
| ATOM | 3996 | C | ASN | B | 597 | 11.980 | 60.236 | 60.783 | 1.00 | 15.43 | B | C |
| ATOM | 3997 | O | ASN | B | 597 | 11.083 | 59.421 | 61.003 | 1.00 | 17.41 | B | O |
| ATOM | 3998 | N | LEU | B | 598 | 12.548 | 60.938 | 61.760 | 1.00 | 14.52 | B | N |
| ATOM | 3999 | CA | LEU | B | 598 | 12.062 | 60.777 | 63.128 | 1.00 | 15.15 | B | C |
| ATOM | 4000 | CB | LEU | B | 598 | 12.927 | 61.565 | 64.118 | 1.00 | 12.48 | B | C |
| ATOM | 4001 | CG | LEU | B | 598 | 14.295 | 60.937 | 64.409 | 1.00 | 13.27 | B | C |
| ATOM | 4002 | CD1 | LEU | B | 598 | 15.173 | 61.908 | 65.182 | 1.00 | 7.29 | B | C |
| ATOM | 4003 | CD2 | LEU | B | 598 | 14.095 | 59.626 | 65.168 | 1.00 | 8.55 | B | C |
| ATOM | 4004 | C | LEU | B | 598 | 10.635 | 61.318 | 63.127 | 1.00 | 16.39 | B | C |
| ATOM | 4005 | O | LEU | B | 598 | 9.821 | 60.977 | 63.983 | 1.00 | 14.02 | B | O |
| ATOM | 4006 | N | LYS | B | 599 | 10.345 | 62.157 | 62.133 | 1.00 | 19.78 | B | N |
| ATOM | 4007 | CA | LYS | B | 599 | 9.027 | 62.766 | 61.954 | 1.00 | 21.69 | B | C |
| ATOM | 4008 | CB | LYS | B | 599 | 9.006 | 63.611 | 60.676 | 1.00 | 24.18 | B | C |
| ATOM | 4009 | CG | LYS | B | 599 | 9.215 | 65.084 | 60.898 | 1.00 | 31.70 | B | C |
| ATOM | 4010 | CD | LYS | B | 599 | 7.885 | 65.821 | 60.995 | 1.00 | 38.86 | B | C |
| ATOM | 4011 | CE | LYS | B | 599 | 7.904 | 66.889 | 62.096 | 1.00 | 38.49 | B | C |
| ATOM | 4012 | NZ | LYS | B | 599 | 7.186 | 66.430 | 63.315 | 1.00 | 36.87 | B | N |
| ATOM | 4013 | C | LYS | B | 599 | 7.952 | 61.701 | 61.826 | 1.00 | 19.88 | B | C |
| ATOM | 4014 | O | LYS | B | 599 | 6.823 | 61.882 | 62.270 | 1.00 | 17.99 | B | O |
| ATOM | 4015 | N | LYS | B | 600 | 8.312 | 60.589 | 61.200 | 1.00 | 20.92 | B | N |
| ATOM | 4016 | CA | LYS | B | 600 | 7.366 | 59.512 | 60.975 | 1.00 | 21.86 | B | C |
| ATOM | 4017 | CB | LYS | B | 600 | 7.739 | 58.767 | 59.693 | 1.00 | 24.24 | B | C |
| ATOM | 4018 | CG | LYS | B | 600 | 7.970 | 59.679 | 58.504 | 1.00 | 26.53 | B | C |
| ATOM | 4019 | CD | LYS | B | 600 | 8.235 | 58.875 | 57.251 | 1.00 | 29.11 | B | C |
| ATOM | 4020 | CE | LYS | B | 600 | 8.532 | 59.781 | 56.070 | 1.00 | 32.84 | B | C |
| ATOM | 4021 | NZ | LYS | B | 600 | 9.174 | 59.033 | 54.948 | 1.00 | 35.17 | B | N |
| ATOM | 4022 | C | LYS | B | 600 | 7.220 | 58.513 | 62.114 | 1.00 | 20.62 | B | C |
| ATOM | 4023 | O | LYS | B | 600 | 6.355 | 57.648 | 62.058 | 1.00 | 22.14 | B | O |
| ATOM | 4024 | N | SER | B | 601 | 8.048 | 58.625 | 63.145 | 1.00 | 17.79 | B | N |
| ATOM | 4025 | CA | SER | B | 601 | 7.973 | 57.681 | 64.255 | 1.00 | 17.16 | B | C |
| ATOM | 4026 | CB | SER | B | 601 | 9.168 | 56.723 | 64.211 | 1.00 | 14.70 | B | C |
| ATOM | 4027 | OG | SER | B | 601 | 9.008 | 55.687 | 65.156 | 1.00 | 16.48 | B | O |
| ATOM | 4028 | C | SER | B | 601 | 7.923 | 58.339 | 65.628 | 1.00 | 16.40 | B | C |
| ATOM | 4029 | O | SER | B | 601 | 8.938 | 58.807 | 66.139 | 1.00 | 16.16 | B | O |
| ATOM | 4030 | N | PRO | B | 602 | 6.732 | 58.392 | 66.241 | 1.00 | 16.74 | B | N |
| ATOM | 4031 | CD | PRO | B | 602 | 5.447 | 57.901 | 65.715 | 1.00 | 16.72 | B | C |
| ATOM | 4032 | CA | PRO | B | 602 | 6.584 | 59.001 | 67.569 | 1.00 | 16.75 | B | C |
| ATOM | 4033 | CB | PRO | B | 602 | 5.091 | 58.864 | 67.868 | 1.00 | 16.61 | B | C |
| ATOM | 4034 | CG | PRO | B | 602 | 4.613 | 57.765 | 66.954 | 1.00 | 18.09 | B | C |
| ATOM | 4035 | C | PRO | B | 602 | 7.443 | 58.285 | 68.611 | 1.00 | 16.59 | B | C |
| ATOM | 4036 | O | PRO | B | 602 | 8.076 | 58.919 | 69.451 | 1.00 | 14.65 | B | O |
| ATOM | 4037 | N | VAL | B | 603 | 7.471 | 56.957 | 68.544 | 1.00 | 18.29 | B | N |
| ATOM | 4038 | CA | VAL | B | 603 | 8.258 | 56.178 | 69.494 | 1.00 | 15.28 | B | C |
| ATOM | 4039 | CB | VAL | B | 603 | 8.054 | 54.657 | 69.311 | 1.00 | 14.18 | B | C |
| ATOM | 4040 | CG1 | VAL | B | 603 | 8.871 | 53.903 | 70.350 | 1.00 | 11.54 | B | C |
| ATOM | 4041 | CG2 | VAL | B | 603 | 6.579 | 54.300 | 69.456 | 1.00 | 5.20 | B | C |
| ATOM | 4042 | C | VAL | B | 603 | 9.745 | 56.487 | 69.387 | 1.00 | 16.57 | B | C |
| ATOM | 4043 | O | VAL | B | 603 | 10.389 | 56.777 | 70.398 | 1.00 | 20.82 | B | O |
| ATOM | 4044 | N | LEU | B | 604 | 10.292 | 56.441 | 68.176 | 1.00 | 12.47 | B | N |
| ATOM | 4045 | CA | LEU | B | 604 | 11.715 | 56.724 | 67.998 | 1.00 | 12.62 | B | C |
| ATOM | 4046 | CB | LEU | B | 604 | 12.174 | 56.316 | 66.593 | 1.00 | 13.54 | B | C |
| ATOM | 4047 | CG | LEU | B | 604 | 12.488 | 54.835 | 66.365 | 1.00 | 9.42 | B | C |
| ATOM | 4048 | CD1 | LEU | B | 604 | 12.491 | 54.539 | 64.879 | 1.00 | 9.08 | B | C |
| ATOM | 4049 | CD2 | LEU | B | 604 | 13.838 | 54.504 | 66.967 | 1.00 | 14.47 | B | C |
| ATOM | 4050 | C | LEU | B | 604 | 12.042 | 58.196 | 68.235 | 1.00 | 11.44 | B | C |
| ATOM | 4051 | O | LEU | B | 604 | 13.113 | 58.526 | 68.755 | 1.00 | 12.27 | B | O |
| ATOM | 4052 | N | GLN | B | 605 | 11.134 | 59.083 | 67.846 | 1.00 | 11.09 | B | N |
| ATOM | 4053 | CA | GLN | B | 605 | 11.352 | 60.512 | 68.045 | 1.00 | 9.87 | B | C |
| ATOM | 4054 | CB | GLN | B | 605 | 10.244 | 61.320 | 67.379 | 1.00 | 7.12 | B | C |
| ATOM | 4055 | CG | GLN | B | 605 | 10.466 | 62.830 | 67.430 | 1.00 | 8.06 | B | C |
| ATOM | 4056 | CD | GLN | B | 605 | 9.294 | 63.597 | 66.843 | 1.00 | 14.22 | B | C |
| ATOM | 4057 | OE1 | GLN | B | 605 | 8.634 | 63.118 | 65.912 | 1.00 | 17.40 | B | O |
| ATOM | 4058 | NE2 | GLN | B | 605 | 9.023 | 64.786 | 67.380 | 1.00 | 7.93 | B | N |
| ATOM | 4059 | C | GLN | B | 605 | 11.395 | 60.838 | 69.536 | 1.00 | 10.83 | B | C |
| ATOM | 4060 | O | GLN | B | 605 | 12.231 | 61.622 | 69.988 | 1.00 | 10.35 | B | O |
| ATOM | 4061 | N | TYR | B | 606 | 10.491 | 60.229 | 70.298 | 1.00 | 12.60 | B | N |
| ATOM | 4062 | CA | TYR | B | 606 | 10.433 | 60.451 | 71.740 | 1.00 | 12.04 | B | C |
| ATOM | 4063 | CB | TYR | B | 606 | 9.174 | 59.791 | 72.326 | 1.00 | 11.90 | B | C |
| ATOM | 4064 | CG | TYR | B | 606 | 8.854 | 60.195 | 73.755 | 1.00 | 15.99 | B | C |
| ATOM | 4065 | CD1 | TYR | B | 606 | 8.755 | 61.541 | 74.120 | 1.00 | 16.23 | B | C |
| ATOM | 4066 | CE1 | TYR | B | 606 | 8.463 | 61.916 | 75.441 | 1.00 | 14.18 | B | C |
| ATOM | 4067 | CD2 | TYR | B | 606 | 8.651 | 59.225 | 74.749 | 1.00 | 14.50 | B | C |
| ATOM | 4068 | CE2 | TYR | B | 606 | 8.359 | 59.590 | 76.072 | 1.00 | 14.30 | B | C |
| ATOM | 4069 | CZ | TYR | B | 606 | 8.268 | 60.935 | 76.408 | 1.00 | 14.89 | B | C |
| ATOM | 4070 | OH | TYR | B | 606 | 7.993 | 61.295 | 77.708 | 1.00 | 16.91 | B | O |
| ATOM | 4071 | C | TYR | B | 606 | 11.699 | 59.884 | 72.388 | 1.00 | 11.52 | B | C |
| ATOM | 4072 | O | TYR | B | 606 | 12.287 | 60.507 | 73.283 | 1.00 | 9.95 | B | O |
| ATOM | 4073 | N | LEU | B | 607 | 12.130 | 58.714 | 71.919 | 1.00 | 9.66 | B | N |
| ATOM | 4074 | CA | LEU | B | 607 | 13.336 | 58.070 | 72.453 | 1.00 | 8.40 | B | C |
| ATOM | 4075 | CB | LEU | B | 607 | 13.547 | 56.708 | 71.792 | 1.00 | 7.38 | B | C |
| ATOM | 4076 | CG | LEU | B | 607 | 12.685 | 55.583 | 72.360 | 1.00 | 8.61 | B | C |
| ATOM | 4077 | CD1 | LEU | B | 607 | 12.921 | 54.314 | 71.582 | 1.00 | 3.64 | B | C |
| ATOM | 4078 | CD2 | LEU | B | 607 | 13.013 | 55.392 | 73.836 | 1.00 | 7.94 | B | C |
| ATOM | 4079 | C | LEU | B | 607 | 14.574 | 58.933 | 72.235 | 1.00 | 6.10 | B | C |
| ATOM | 4080 | O | LEU | B | 607 | 15.473 | 58.962 | 73.064 | 1.00 | 7.75 | B | O |
| ATOM | 4081 | N | PHE | B | 608 | 14.614 | 59.639 | 71.112 | 1.00 | 8.27 | B | N |
| ATOM | 4082 | CA | PHE | B | 608 | 15.744 | 60.509 | 70.804 | 1.00 | 7.76 | B | C |
| ATOM | 4083 | CB | PHE | B | 608 | 15.707 | 60.936 | 69.329 | 1.00 | 5.87 | B | C |
| ATOM | 4084 | CG | PHE | B | 608 | 16.510 | 60.041 | 68.419 | 1.00 | 4.27 | B | C |
| ATOM | 4085 | CD1 | PHE | B | 608 | 16.129 | 58.724 | 68.199 | 1.00 | 5.43 | B | C |
| ATOM | 4086 | CD2 | PHE | B | 608 | 17.659 | 60.512 | 67.795 | 1.00 | 5.26 | B | C |
| ATOM | 4087 | CE1 | PHE | B | 608 | 16.887 | 57.887 | 67.369 | 1.00 | 6.43 | B | C |
| ATOM | 4088 | CE2 | PHE | B | 608 | 18.419 | 59.685 | 66.967 | 1.00 | 3.17 | B | C |
| ATOM | 4089 | CZ | PHE | B | 608 | 18.032 | 58.371 | 66.755 | 1.00 | 2.29 | B | C |
| ATOM | 4090 | C | PHE | B | 608 | 15.721 | 61.734 | 71.709 | 1.00 | 7.74 | B | C |
| ATOM | 4091 | O | PHE | B | 608 | 16.754 | 62.355 | 71.962 | 1.00 | 9.36 | B | O |
| ATOM | 4092 | N | PHE | B | 609 | 14.534 | 62.091 | 72.188 | 1.00 | 10.21 | B | N |
| ATOM | 4093 | CA | PHE | B | 609 | 14.393 | 63.228 | 73.086 | 1.00 | 7.22 | B | C |
| ATOM | 4094 | CB | PHE | B | 609 | 12.935 | 63.687 | 73.158 | 1.00 | 9.38 | B | C |
| ATOM | 4095 | CG | PHE | B | 609 | 12.660 | 64.629 | 74.297 | 1.00 | 10.16 | B | C |
| ATOM | 4096 | CD1 | PHE | B | 609 | 12.053 | 64.170 | 75.470 | 1.00 | 11.36 | B | C |
| ATOM | 4097 | CD2 | PHE | B | 609 | 13.069 | 65.960 | 74.230 | 1.00 | 9.82 | B | C |
| ATOM | 4098 | CE1 | PHE | B | 609 | 11.862 | 65.020 | 76.566 | 1.00 | 9.03 | B | C |
| ATOM | 4099 | CE2 | PHE | B | 609 | 12.884 | 66.825 | 75.323 | 1.00 | 8.03 | B | C |
| ATOM | 4100 | CZ | PHE | B | 609 | 12.280 | 66.349 | 76.493 | 1.00 | 8.31 | B | C |
| ATOM | 4101 | C | PHE | B | 609 | 14.849 | 62.775 | 74.472 | 1.00 | 10.19 | B | C |
| ATOM | 4102 | O | PHE | B | 609 | 15.680 | 63.425 | 75.111 | 1.00 | 11.63 | B | O |
| ATOM | 4103 | N | LEU | B | 610 | 14.305 | 61.651 | 74.930 | 1.00 | 7.90 | B | N |
| ATOM | 4104 | CA | LEU | B | 610 | 14.652 | 61.108 | 76.238 | 1.00 | 8.51 | B | C |
| ATOM | 4105 | CB | LEU | B | 610 | 13.906 | 59.801 | 76.492 | 1.00 | 4.45 | B | C |
| ATOM | 4106 | CG | LEU | B | 610 | 12.391 | 59.852 | 76.608 | 1.00 | 5.48 | B | C |
| ATOM | 4107 | CD1 | LEU | B | 610 | 11.862 | 58.438 | 76.757 | 1.00 | 5.62 | B | C |
| ATOM | 4108 | CD2 | LEU | B | 610 | 11.990 | 60.720 | 77.790 | 1.00 | 4.24 | B | C |
| ATOM | 4109 | C | LEU | B | 610 | 16.148 | 60.848 | 76.389 | 1.00 | 12.20 | B | C |
| ATOM | 4110 | O | LEU | B | 610 | 16.739 | 61.160 | 77.434 | 1.00 | 15.14 | B | O |
| ATOM | 4111 | N | ALA | B | 611 | 16.758 | 60.256 | 75.362 | 1.00 | 11.22 | B | N |
| ATOM | 4112 | CA | ALA | B | 611 | 18.191 | 59.959 | 75.391 | 1.00 | 9.11 | B | C |
| ATOM | 4113 | CB | ALA | B | 611 | 18.499 | 58.797 | 74.451 | 1.00 | 6.97 | B | C |
| ATOM | 4114 | C | ALA | B | 611 | 19.028 | 61.179 | 75.008 | 1.00 | 6.50 | B | C |
| ATOM | 4115 | O | ALA | B | 611 | 20.247 | 61.170 | 75.124 | 1.00 | 9.36 | B | O |
| ATOM | 4116 | N | GLN | B | 612 | 18.362 | 62.229 | 74.548 | 1.00 | 9.83 | B | N |
| ATOM | 4117 | CA | GLN | B | 612 | 19.025 | 63.464 | 74.138 | 1.00 | 11.80 | B | C |
| ATOM | 4118 | CB | GLN | B | 612 | 19.609 | 64.170 | 75.363 | 1.00 | 11.24 | B | C |
| ATOM | 4119 | CG | GLN | B | 612 | 18.594 | 64.993 | 76.141 | 1.00 | 14.19 | B | C |
| ATOM | 4120 | CD | GLN | B | 612 | 17.949 | 66.076 | 75.292 | 1.00 | 19.34 | B | C |
| ATOM | 4121 | OE1 | GLN | B | 612 | 18.586 | 67.073 | 74.943 | 1.00 | 15.47 | B | O |
| ATOM | 4122 | NE2 | GLN | B | 612 | 16.680 | 65.884 | 74.951 | 1.00 | 16.73 | B | N |
| ATOM | 4123 | C | GLN | B | 612 | 20.124 | 63.223 | 73.096 | 1.00 | 13.76 | B | C |
| ATOM | 4124 | O | GLN | B | 612 | 21.233 | 63.747 | 73.206 | 1.00 | 14.74 | B | O |
| ATOM | 4125 | N | ILE | B | 613 | 19.807 | 62.434 | 72.076 | 1.00 | 14.33 | B | N |
| ATOM | 4126 | CA | ILE | B | 613 | 20.778 | 62.122 | 71.038 | 1.00 | 11.43 | B | C |
| ATOM | 4127 | CB | ILE | B | 613 | 20.311 | 60.907 | 70.210 | 1.00 | 9.95 | B | C |
| ATOM | 4128 | CG2 | ILE | B | 613 | 21.416 | 60.471 | 69.260 | 1.00 | 11.27 | B | C |
| ATOM | 4129 | CG1 | ILE | B | 613 | 19.909 | 59.765 | 71.146 | 1.00 | 8.74 | B | C |
| ATOM | 4130 | CD1 | ILE | B | 613 | 19.545 | 58.452 | 70.447 | 1.00 | 2.19 | B | C |
| ATOM | 4131 | C | ILE | B | 613 | 21.003 | 63.313 | 70.103 | 1.00 | 11.73 | B | C |
| ATOM | 4132 | O | ILE | B | 613 | 20.071 | 63.784 | 69.456 | 1.00 | 14.23 | B | O |
| ATOM | 4133 | N | PRO | B | 614 | 22.240 | 63.825 | 70.032 | 1.00 | 11.28 | B | N |
| ATOM | 4134 | CD | PRO | B | 614 | 23.429 | 63.374 | 70.775 | 1.00 | 10.81 | B | C |
| ATOM | 4135 | CA | PRO | B | 614 | 22.553 | 64.963 | 69.159 | 1.00 | 10.69 | B | C |
| ATOM | 4136 | CB | PRO | B | 614 | 24.047 | 65.188 | 69.375 | 1.00 | 9.01 | B | C |
| ATOM | 4137 | CG | PRO | B | 614 | 24.348 | 64.540 | 70.666 | 1.00 | 5.00 | B | C |
| ATOM | 4138 | C | PRO | B | 614 | 22.233 | 64.664 | 67.693 | 1.00 | 11.32 | B | C |
| ATOM | 4139 | O | PRO | B | 614 | 22.537 | 63.583 | 67.190 | 1.00 | 9.40 | B | O |
| ATOM | 4140 | N | ILE | B | 615 | 21.621 | 65.628 | 67.015 | 1.00 | 11.66 | B | N |
| ATOM | 4141 | CA | ILE | B | 615 | 21.249 | 65.463 | 65.609 | 1.00 | 10.61 | B | C |
| ATOM | 4142 | CB | ILE | B | 615 | 19.713 | 65.375 | 65.442 | 1.00 | 10.90 | B | C |
| ATOM | 4143 | CG2 | ILE | B | 615 | 19.351 | 65.243 | 63.970 | 1.00 | 11.66 | B | C |
| ATOM | 4144 | CG1 | ILE | B | 615 | 19.159 | 64.186 | 66.230 | 1.00 | 7.15 | B | C |
| ATOM | 4145 | CD1 | ILE | B | 615 | 17.654 | 64.254 | 66.429 | 1.00 | 5.13 | B | C |
| ATOM | 4146 | C | ILE | B | 615 | 21.736 | 66.652 | 64.800 | 1.00 | 9.10 | B | C |
| ATOM | 4147 | O | ILE | B | 615 | 21.333 | 67.781 | 65.062 | 1.00 | 11.95 | B | O |
| ATOM | 4148 | N | ALA | B | 616 | 22.612 | 66.413 | 63.831 | 1.00 | 11.53 | B | N |
| ATOM | 4149 | CA | ALA | B | 616 | 23.112 | 67.513 | 62.995 | 1.00 | 11.72 | B | C |
| ATOM | 4150 | CB | ALA | B | 616 | 24.531 | 67.235 | 62.543 | 1.00 | 10.37 | B | C |
| ATOM | 4151 | C | ALA | B | 616 | 22.194 | 67.658 | 61.784 | 1.00 | 9.51 | B | C |
| ATOM | 4152 | O | ALA | B | 616 | 22.131 | 66.770 | 60.927 | 1.00 | 9.07 | B | O |
| ATOM | 4153 | N | MET | B | 617 | 21.465 | 68.766 | 61.719 | 1.00 | 9.92 | B | N |
| ATOM | 4154 | CA | MET | B | 617 | 20.549 | 68.982 | 60.603 | 1.00 | 11.08 | B | C |
| ATOM | 4155 | CB | MET | B | 617 | 19.200 | 69.492 | 61.118 | 1.00 | 8.92 | B | C |
| ATOM | 4156 | CG | MET | B | 617 | 18.677 | 68.735 | 62.340 | 1.00 | 13.19 | B | C |
| ATOM | 4157 | SD | MET | B | 617 | 16.888 | 68.493 | 62.322 | 1.00 | 21.20 | B | S |
| ATOM | 4158 | CE | MET | B | 617 | 16.428 | 69.733 | 63.374 | 1.00 | 24.19 | B | C |
| ATOM | 4159 | C | MET | B | 617 | 21.115 | 69.947 | 59.565 | 1.00 | 10.06 | B | C |
| ATOM | 4160 | O | MET | B | 617 | 22.001 | 70.757 | 59.866 | 1.00 | 7.18 | B | O |
| ATOM | 4161 | N | SER | B | 618 | 20.585 | 69.846 | 58.346 | 1.00 | 12.95 | B | N |
| ATOM | 4162 | CA | SER | B | 618 | 21.001 | 70.671 | 57.204 | 1.00 | 11.71 | B | C |
| ATOM | 4163 | CB | SER | B | 618 | 22.040 | 69.929 | 56.363 | 1.00 | 10.21 | B | C |
| ATOM | 4164 | OG | SER | B | 618 | 23.007 | 69.287 | 57.173 | 1.00 | 13.21 | B | O |
| ATOM | 4165 | C | SER | B | 618 | 19.808 | 70.971 | 56.310 | 1.00 | 12.91 | B | C |
| ATOM | 4166 | O | SER | B | 618 | 19.634 | 70.337 | 55.280 | 1.00 | 14.28 | B | O |
| ATOM | 4167 | N | PRO | B | 619 | 18.960 | 71.925 | 56.699 | 1.00 | 13.30 | B | N |
| ATOM | 4168 | CD | PRO | B | 619 | 19.032 | 72.700 | 57.948 | 1.00 | 11.99 | B | C |
| ATOM | 4169 | CA | PRO | B | 619 | 17.782 | 72.282 | 55.901 | 1.00 | 12.29 | B | C |
| ATOM | 4170 | CB | PRO | B | 619 | 17.137 | 73.413 | 56.700 | 1.00 | 12.20 | B | C |
| ATOM | 4171 | CG | PRO | B | 619 | 17.633 | 73.215 | 58.098 | 1.00 | 11.57 | B | C |
| ATOM | 4172 | C | PRO | B | 619 | 18.030 | 72.679 | 54.436 | 1.00 | 13.69 | B | C |
| ATOM | 4173 | O | PRO | B | 619 | 17.219 | 72.352 | 53.573 | 1.00 | 12.94 | B | O |
| ATOM | 4174 | N | LEU | B | 620 | 19.128 | 73.381 | 54.149 | 1.00 | 14.24 | B | N |
| ATOM | 4175 | CA | LEU | B | 620 | 19.416 | 73.796 | 52.774 | 1.00 | 14.70 | B | C |
| ATOM | 4176 | CB | LEU | B | 620 | 20.566 | 74.806 | 52.747 | 1.00 | 12.21 | B | C |
| ATOM | 4177 | CG | LEU | B | 620 | 20.161 | 76.220 | 53.183 | 1.00 | 13.19 | B | C |
| ATOM | 4178 | CD1 | LEU | B | 620 | 21.380 | 77.122 | 53.293 | 1.00 | 10.01 | B | C |
| ATOM | 4179 | CD2 | LEU | B | 620 | 19.167 | 76.783 | 52.186 | 1.00 | 11.10 | B | C |
| ATOM | 4180 | C | LEU | B | 620 | 19.750 | 72.597 | 51.889 | 1.00 | 16.44 | B | C |
| ATOM | 4181 | O | LEU | B | 620 | 19.344 | 72.523 | 50.721 | 1.00 | 17.58 | B | O |
| ATOM | 4182 | N | SER | B | 621 | 20.500 | 71.657 | 52.446 | 1.00 | 17.05 | B | N |
| ATOM | 4183 | CA | SER | B | 621 | 20.857 | 70.452 | 51.718 | 1.00 | 15.21 | B | C |
| ATOM | 4184 | CB | SER | B | 621 | 21.856 | 69.639 | 52.530 | 1.00 | 14.23 | B | C |
| ATOM | 4185 | OG | SER | B | 621 | 22.028 | 68.346 | 51.998 | 1.00 | 16.97 | B | O |
| ATOM | 4186 | C | SER | B | 621 | 19.585 | 69.645 | 51.458 | 1.00 | 17.04 | B | C |
| ATOM | 4187 | O | SER | B | 621 | 19.353 | 69.192 | 50.336 | 1.00 | 17.49 | B | O |
| ATOM | 4188 | N | ASN | B | 622 | 18.748 | 69.482 | 52.485 | 1.00 | 16.43 | B | N |
| ATOM | 4189 | CA | ASN | B | 622 | 17.493 | 68.733 | 52.347 | 1.00 | 14.60 | B | C |
| ATOM | 4190 | CB | ASN | B | 622 | 16.735 | 68.677 | 53.679 | 1.00 | 17.04 | B | C |
| ATOM | 4191 | CG | ASN | B | 622 | 17.552 | 68.071 | 54.811 | 1.00 | 18.49 | B | C |
| ATOM | 4192 | OD1 | ASN | B | 622 | 17.312 | 68.366 | 55.983 | 1.00 | 18.56 | B | O |
| ATOM | 4193 | ND2 | ASN | B | 622 | 18.512 | 67.217 | 54.469 | 1.00 | 18.32 | B | N |
| ATOM | 4194 | C | ASN | B | 622 | 16.575 | 69.365 | 51.305 | 1.00 | 15.16 | B | C |
| ATOM | 4195 | O | ASN | B | 622 | 15.898 | 68.662 | 50.554 | 1.00 | 15.42 | B | O |
| ATOM | 4196 | N | ASN | B | 623 | 16.543 | 70.694 | 51.281 | 1.00 | 13.44 | B | N |
| ATOM | 4197 | CA | ASN | B | 623 | 15.708 | 71.441 | 50.346 | 1.00 | 18.18 | B | C |
| ATOM | 4198 | CB | ASN | B | 623 | 15.796 | 72.939 | 50.680 | 1.00 | 16.05 | B | C |
| ATOM | 4199 | CG | ASN | B | 623 | 15.049 | 73.820 | 49.693 | 1.00 | 13.48 | B | C |
| ATOM | 4200 | OD1 | ASN | B | 623 | 15.655 | 74.645 | 49.012 | 1.00 | 13.08 | B | O |
| ATOM | 4201 | ND2 | ASN | B | 623 | 13.735 | 73.661 | 49.624 | 1.00 | 9.21 | B | N |
| ATOM | 4202 | C | ASN | B | 623 | 16.141 | 71.177 | 48.907 | 1.00 | 23.03 | B | C |
| ATOM | 4203 | O | ASN | B | 623 | 15.336 | 71.202 | 47.987 | 1.00 | 24.13 | B | O |
| ATOM | 4204 | N | SER | B | 624 | 17.423 | 70.908 | 48.723 | 1.00 | 29.01 | B | N |
| ATOM | 4205 | CA | SER | B | 624 | 17.961 | 70.645 | 47.396 | 1.00 | 33.14 | B | C |
| ATOM | 4206 | CB | SER | B | 624 | 19.387 | 71.181 | 47.301 | 1.00 | 33.17 | B | C |
| ATOM | 4207 | OG | SER | B | 624 | 19.507 | 72.122 | 46.255 | 1.00 | 36.57 | B | O |
| ATOM | 4208 | C | SER | B | 624 | 17.993 | 69.161 | 47.075 | 1.00 | 36.67 | B | C |
| ATOM | 4209 | O | SER | B | 624 | 18.277 | 68.779 | 45.937 | 1.00 | 37.42 | B | O |
| ATOM | 4210 | N | LEU | B | 625 | 17.681 | 68.326 | 48.063 | 1.00 | 39.45 | B | N |
| ATOM | 4211 | CA | LEU | B | 625 | 17.759 | 66.888 | 47.864 | 1.00 | 40.62 | B | C |
| ATOM | 4212 | CB | LEU | B | 625 | 18.931 | 66.358 | 48.699 | 1.00 | 41.41 | B | C |
| ATOM | 4213 | CG | LEU | B | 625 | 20.115 | 65.647 | 48.033 | 1.00 | 44.07 | B | C |
| ATOM | 4214 | CD1 | LEU | B | 625 | 19.689 | 65.077 | 46.698 | 1.00 | 49.45 | B | C |
| ATOM | 4215 | CD2 | LEU | B | 625 | 21.267 | 66.606 | 47.841 | 1.00 | 44.50 | B | C |
| ATOM | 4216 | C | LEU | B | 625 | 16.504 | 66.036 | 48.138 | 1.00 | 40.80 | B | C |
| ATOM | 4217 | O | LEU | B | 625 | 16.127 | 65.218 | 47.304 | 1.00 | 41.03 | B | O |
| ATOM | 4218 | N | PHE | B | 626 | 15.858 | 66.218 | 49.288 | 1.00 | 40.88 | B | N |
| ATOM | 4219 | CA | PHE | B | 626 | 14.697 | 65.392 | 49.630 | 1.00 | 38.39 | B | C |
| ATOM | 4220 | CB | PHE | B | 626 | 15.120 | 64.313 | 50.635 | 1.00 | 37.27 | B | C |
| ATOM | 4221 | CG | PHE | B | 626 | 16.105 | 63.311 | 50.091 | 1.00 | 38.46 | B | C |
| ATOM | 4222 | CD1 | PHE | B | 626 | 15.663 | 62.178 | 49.413 | 1.00 | 36.47 | B | C |
| ATOM | 4223 | CD2 | PHE | B | 626 | 17.475 | 63.483 | 50.281 | 1.00 | 40.35 | B | C |
| ATOM | 4224 | CE1 | PHE | B | 626 | 16.570 | 61.232 | 48.936 | 1.00 | 38.66 | B | C |
| ATOM | 4225 | CE2 | PHE | B | 626 | 18.396 | 62.540 | 49.806 | 1.00 | 37.49 | B | C |
| ATOM | 4226 | CZ | PHE | B | 626 | 17.942 | 61.415 | 49.133 | 1.00 | 38.12 | B | C |
| ATOM | 4227 | C | PHE | B | 626 | 13.451 | 66.091 | 50.181 | 1.00 | 37.22 | B | C |
| ATOM | 4228 | O | PHE | B | 626 | 12.343 | 65.629 | 49.934 | 1.00 | 38.84 | B | O |
| ATOM | 4229 | N | LEU | B | 627 | 13.621 | 67.188 | 50.919 | 1.00 | 35.53 | B | N |
| ATOM | 4230 | CA | LEU | B | 627 | 12.484 | 67.889 | 51.516 | 1.00 | 33.39 | B | C |
| ATOM | 4231 | CB | LEU | B | 627 | 12.458 | 67.627 | 53.025 | 1.00 | 32.91 | B | C |
| ATOM | 4232 | CG | LEU | B | 627 | 11.195 | 67.159 | 53.751 | 1.00 | 29.47 | B | C |
| ATOM | 4233 | CD1 | LEU | B | 627 | 11.279 | 67.631 | 55.192 | 1.00 | 28.18 | B | C |
| ATOM | 4234 | CD2 | LEU | B | 627 | 9.945 | 67.689 | 53.078 | 1.00 | 26.31 | B | C |
| ATOM | 4235 | C | LEU | B | 627 | 12.521 | 69.391 | 51.289 | 1.00 | 32.96 | B | C |
| ATOM | 4236 | O | LEU | B | 627 | 13.539 | 70.034 | 51.523 | 1.00 | 34.49 | B | O |
| ATOM | 4237 | N | GLU | B | 628 | 11.395 | 69.949 | 50.859 | 1.00 | 31.43 | B | N |
| ATOM | 4238 | CA | GLU | B | 628 | 11.290 | 71.385 | 50.622 | 1.00 | 32.21 | B | C |
| ATOM | 4239 | CB | GLU | B | 628 | 9.903 | 71.695 | 50.055 | 1.00 | 37.81 | B | C |
| ATOM | 4240 | CG | GLU | B | 628 | 9.340 | 73.053 | 50.411 | 1.00 | 46.48 | B | C |
| ATOM | 4241 | CD | GLU | B | 628 | 7.864 | 73.174 | 50.063 | 1.00 | 51.86 | B | C |
| ATOM | 4242 | OE1 | GLU | B | 628 | 7.252 | 72.153 | 49.673 | 1.00 | 50.91 | B | O |
| ATOM | 4243 | OE2 | GLU | B | 628 | 7.317 | 74.294 | 50.182 | 1.00 | 55.20 | B | O |
| ATOM | 4244 | C | GLU | B | 628 | 11.532 | 72.131 | 51.940 | 1.00 | 29.11 | B | C |
| ATOM | 4245 | O | GLU | B | 628 | 11.044 | 71.712 | 52.988 | 1.00 | 27.66 | B | O |
| ATOM | 4246 | N | TYR | B | 629 | 12.273 | 73.236 | 51.883 | 1.00 | 24.21 | B | N |
| ATOM | 4247 | CA | TYR | B | 629 | 12.607 | 73.998 | 53.083 | 1.00 | 21.61 | B | C |
| ATOM | 4248 | CB | TYR | B | 629 | 13.193 | 75.365 | 52.720 | 1.00 | 19.65 | B | C |
| ATOM | 4249 | CG | TYR | B | 629 | 14.138 | 75.874 | 53.788 | 1.00 | 21.15 | B | C |
| ATOM | 4250 | CD1 | TYR | B | 629 | 13.657 | 76.538 | 54.921 | 1.00 | 19.89 | B | C |
| ATOM | 4251 | CE1 | TYR | B | 629 | 14.517 | 76.927 | 55.945 | 1.00 | 19.07 | B | C |
| ATOM | 4252 | CD2 | TYR | B | 629 | 15.505 | 75.623 | 53.707 | 1.00 | 18.22 | B | C |
| ATOM | 4253 | CE2 | TYR | B | 629 | 16.369 | 76.007 | 54.723 | 1.00 | 21.67 | B | C |
| ATOM | 4254 | CZ | TYR | B | 629 | 15.872 | 76.653 | 55.840 | 1.00 | 22.47 | B | C |
| ATOM | 4255 | OH | TYR | B | 629 | 16.743 | 76.995 | 56.853 | 1.00 | 24.76 | B | O |
| ATOM | 4256 | C | TYR | B | 629 | 11.512 | 74.204 | 54.121 | 1.00 | 21.80 | B | C |
| ATOM | 4257 | O | TYR | B | 629 | 11.643 | 73.763 | 55.263 | 1.00 | 21.41 | B | O |
| ATOM | 4258 | N | ALA | B | 630 | 10.436 | 74.876 | 53.732 | 1.00 | 22.89 | B | N |
| ATOM | 4259 | CA | ALA | B | 630 | 9.343 | 75.162 | 54.656 | 1.00 | 23.25 | B | C |
| ATOM | 4260 | CB | ALA | B | 630 | 8.276 | 76.003 | 53.960 | 1.00 | 22.76 | B | C |
| ATOM | 4261 | C | ALA | B | 630 | 8.700 | 73.929 | 55.289 | 1.00 | 23.11 | B | C |
| ATOM | 4262 | O | ALA | B | 630 | 7.883 | 74.056 | 56.199 | 1.00 | 22.93 | B | O |
| ATOM | 4263 | N | LYS | B | 631 | 9.069 | 72.743 | 54.820 | 1.00 | 19.37 | B | N |
| ATOM | 4264 | CA | LYS | B | 631 | 8.504 | 71.516 | 55.364 | 1.00 | 20.86 | B | C |
| ATOM | 4265 | CB | LYS | B | 631 | 8.095 | 70.571 | 54.226 | 1.00 | 24.53 | B | C |
| ATOM | 4266 | CG | LYS | B | 631 | 6.698 | 70.813 | 53.653 | 1.00 | 31.18 | B | C |
| ATOM | 4267 | CD | LYS | B | 631 | 6.311 | 72.296 | 53.683 | 1.00 | 38.76 | B | C |
| ATOM | 4268 | CE | LYS | B | 631 | 4.790 | 72.497 | 53.701 | 1.00 | 43.32 | B | C |
| ATOM | 4269 | NZ | LYS | B | 631 | 4.351 | 73.642 | 52.835 | 1.00 | 42.85 | B | N |
| ATOM | 4270 | C | LYS | B | 631 | 9.495 | 70.804 | 56.288 | 1.00 | 19.88 | B | C |
| ATOM | 4271 | O | LYS | B | 631 | 9.216 | 69.715 | 56.790 | 1.00 | 18.23 | B | O |
| ATOM | 4272 | N | ASN | B | 632 | 10.649 | 71.422 | 56.515 | 1.00 | 17.30 | B | N |
| ATOM | 4273 | CA | ASN | B | 632 | 11.666 | 70.818 | 57.369 | 1.00 | 16.76 | B | C |
| ATOM | 4274 | CB | ASN | B | 632 | 12.982 | 71.587 | 57.248 | 1.00 | 16.95 | B | C |
| ATOM | 4275 | CG | ASN | B | 632 | 14.174 | 70.741 | 57.619 | 1.00 | 16.71 | B | C |
| ATOM | 4276 | OD1 | ASN | B | 632 | 14.905 | 70.280 | 56.752 | 1.00 | 21.42 | B | O |
| ATOM | 4277 | ND2 | ASN | B | 632 | 14.372 | 70.520 | 58.914 | 1.00 | 14.46 | B | N |
| ATOM | 4278 | C | ASN | B | 632 | 11.266 | 70.739 | 58.841 | 1.00 | 15.76 | B | C |
| ATOM | 4279 | O | ASN | B | 632 | 10.783 | 71.712 | 59.414 | 1.00 | 17.49 | B | O |
| ATOM | 4280 | N | PRO | B | 633 | 11.467 | 69.569 | 59.473 | 1.00 | 16.46 | B | N |
| ATOM | 4281 | CD | PRO | B | 633 | 12.007 | 68.325 | 58.897 | 1.00 | 14.87 | B | C |
| ATOM | 4282 | CA | PRO | B | 633 | 11.115 | 69.416 | 60.889 | 1.00 | 16.50 | B | C |
| ATOM | 4283 | CB | PRO | B | 633 | 11.080 | 67.904 | 61.087 | 1.00 | 16.66 | B | C |
| ATOM | 4284 | CG | PRO | B | 633 | 11.991 | 67.365 | 60.047 | 1.00 | 15.23 | B | C |
| ATOM | 4285 | C | PRO | B | 633 | 12.088 | 70.090 | 61.860 | 1.00 | 15.78 | B | C |
| ATOM | 4286 | O | PRO | B | 633 | 11.962 | 69.926 | 63.063 | 1.00 | 17.61 | B | O |
| ATOM | 4287 | N | PHE | B | 634 | 13.045 | 70.856 | 61.343 | 1.00 | 14.01 | B | N |
| ATOM | 4288 | CA | PHE | B | 634 | 14.021 | 71.525 | 62.192 | 1.00 | 12.75 | B | C |
| ATOM | 4289 | CB | PHE | B | 634 | 14.921 | 72.447 | 61.358 | 1.00 | 11.75 | B | C |
| ATOM | 4290 | CG | PHE | B | 634 | 15.810 | 73.339 | 62.192 | 1.00 | 14.11 | B | C |
| ATOM | 4291 | CD1 | PHE | B | 634 | 15.396 | 74.622 | 62.540 | 1.00 | 14.62 | B | C |
| ATOM | 4292 | CD2 | PHE | B | 634 | 17.033 | 72.879 | 62.675 | 1.00 | 14.00 | B | C |
| ATOM | 4293 | CE1 | PHE | B | 634 | 16.183 | 75.435 | 63.363 | 1.00 | 11.34 | B | C |
| ATOM | 4294 | CE2 | PHE | B | 634 | 17.826 | 73.685 | 63.501 | 1.00 | 13.99 | B | C |
| ATOM | 4295 | CZ | PHE | B | 634 | 17.393 | 74.967 | 63.844 | 1.00 | 11.23 | B | C |
| ATOM | 4296 | C | PHE | B | 634 | 13.401 | 72.318 | 63.347 | 1.00 | 14.95 | B | C |
| ATOM | 4297 | O | PHE | B | 634 | 13.798 | 72.142 | 64.498 | 1.00 | 14.66 | B | O |
| ATOM | 4298 | N | LEU | B | 635 | 12.442 | 73.188 | 63.049 | 1.00 | 11.26 | B | N |
| ATOM | 4299 | CA | LEU | B | 635 | 11.805 | 73.991 | 64.086 | 1.00 | 11.60 | B | C |
| ATOM | 4300 | CB | LEU | B | 635 | 10.829 | 74.991 | 63.465 | 1.00 | 9.99 | B | C |
| ATOM | 4301 | CG | LEU | B | 635 | 10.178 | 75.978 | 64.434 | 1.00 | 8.88 | B | C |
| ATOM | 4302 | CD1 | LEU | B | 635 | 11.258 | 76.841 | 65.076 | 1.00 | 5.70 | B | C |
| ATOM | 4303 | CD2 | LEU | B | 635 | 9.172 | 76.838 | 63.702 | 1.00 | 3.17 | B | C |
| ATOM | 4304 | C | LEU | B | 635 | 11.057 | 73.108 | 65.081 | 1.00 | 13.18 | B | C |
| ATOM | 4305 | O | LEU | B | 635 | 11.243 | 73.222 | 66.289 | 1.00 | 14.46 | B | O |
| ATOM | 4306 | N | ASP | B | 636 | 10.203 | 72.231 | 64.569 | 1.00 | 11.41 | B | N |
| ATOM | 4307 | CA | ASP | B | 636 | 9.439 | 71.327 | 65.415 | 1.00 | 11.21 | B | C |
| ATOM | 4308 | CB | ASP | B | 636 | 8.745 | 70.275 | 64.552 | 1.00 | 12.34 | B | C |
| ATOM | 4309 | CG | ASP | B | 636 | 7.694 | 69.500 | 65.314 | 1.00 | 14.32 | B | C |
| ATOM | 4310 | OD1 | ASP | B | 636 | 6.834 | 70.129 | 65.962 | 1.00 | 16.95 | B | O |
| ATOM | 4311 | OD2 | ASP | B | 636 | 7.722 | 68.258 | 65.264 | 1.00 | 13.89 | B | O |
| ATOM | 4312 | C | ASP | B | 636 | 10.351 | 70.635 | 66.431 | 1.00 | 14.10 | B | C |
| ATOM | 4313 | O | ASP | B | 636 | 10.090 | 70.648 | 67.642 | 1.00 | 13.64 | B | O |
| ATOM | 4314 | N | PHE | B | 637 | 11.422 | 70.029 | 65.932 | 1.00 | 11.77 | B | N |
| ATOM | 4315 | CA | PHE | B | 637 | 12.375 | 69.331 | 66.778 | 1.00 | 10.34 | B | C |
| ATOM | 4316 | CB | PHE | B | 637 | 13.463 | 68.688 | 65.912 | 1.00 | 9.71 | B | C |
| ATOM | 4317 | CG | PHE | B | 637 | 12.991 | 67.499 | 65.105 | 1.00 | 6.01 | B | C |
| ATOM | 4318 | CD1 | PHE | B | 637 | 11.662 | 67.094 | 65.131 | 1.00 | 4.60 | B | C |
| ATOM | 4319 | CD2 | PHE | B | 637 | 13.893 | 66.773 | 64.331 | 1.00 | 9.36 | B | C |
| ATOM | 4320 | CE1 | PHE | B | 637 | 11.237 | 65.978 | 64.398 | 1.00 | 5.36 | B | C |
| ATOM | 4321 | CE2 | PHE | B | 637 | 13.481 | 65.659 | 63.598 | 1.00 | 6.26 | B | C |
| ATOM | 4322 | CZ | PHE | B | 637 | 12.152 | 65.261 | 63.631 | 1.00 | 4.45 | B | C |
| ATOM | 4323 | C | PHE | B | 637 | 13.011 | 70.278 | 67.800 | 1.00 | 12.82 | B | C |
| ATOM | 4324 | O | PHE | B | 637 | 13.150 | 69.935 | 68.974 | 1.00 | 13.80 | B | O |
| ATOM | 4325 | N | LEU | B | 638 | 13.388 | 71.472 | 67.364 | 1.00 | 12.42 | B | N |
| ATOM | 4326 | CA | LEU | B | 638 | 14.006 | 72.431 | 68.266 | 1.00 | 13.57 | B | C |
| ATOM | 4327 | CB | LEU | B | 638 | 14.449 | 73.680 | 67.498 | 1.00 | 15.74 | B | C |
| ATOM | 4328 | CG | LEU | B | 638 | 15.148 | 74.719 | 68.382 | 1.00 | 19.73 | B | C |
| ATOM | 4329 | CD1 | LEU | B | 638 | 16.613 | 74.350 | 68.526 | 1.00 | 18.96 | B | C |
| ATOM | 4330 | CD2 | LEU | B | 638 | 15.001 | 76.107 | 67.793 | 1.00 | 16.59 | B | C |
| ATOM | 4331 | C | LEU | B | 638 | 13.077 | 72.848 | 69.403 | 1.00 | 14.12 | B | C |
| ATOM | 4332 | O | LEU | B | 638 | 13.485 | 72.893 | 70.565 | 1.00 | 15.98 | B | O |
| ATOM | 4333 | N | GLN | B | 639 | 11.832 | 73.166 | 69.068 | 1.00 | 14.17 | B | N |
| ATOM | 4334 | CA | GLN | B | 639 | 10.867 | 73.590 | 70.075 | 1.00 | 15.00 | B | C |
| ATOM | 4335 | CB | GLN | B | 639 | 9.566 | 74.024 | 69.404 | 1.00 | 12.04 | B | C |
| ATOM | 4336 | CG | GLN | B | 639 | 9.680 | 75.305 | 68.607 | 1.00 | 11.93 | B | C |
| ATOM | 4337 | CD | GLN | B | 639 | 8.380 | 75.659 | 67.923 | 1.00 | 14.32 | B | C |
| ATOM | 4338 | OE1 | GLN | B | 639 | 7.638 | 74.779 | 67.502 | 1.00 | 16.43 | B | O |
| ATOM | 4339 | NE2 | GLN | B | 639 | 8.096 | 76.949 | 67.811 | 1.00 | 13.44 | B | N |
| ATOM | 4340 | C | GLN | B | 639 | 10.575 | 72.477 | 71.076 | 1.00 | 15.90 | B | C |
| ATOM | 4341 | O | GLN | B | 639 | 10.525 | 72.712 | 72.280 | 1.00 | 14.76 | B | O |
| ATOM | 4342 | N | LYS | B | 640 | 10.383 | 71.267 | 70.558 | 1.00 | 16.57 | B | N |
| ATOM | 4343 | CA | LYS | B | 640 | 10.093 | 70.099 | 71.378 | 1.00 | 14.30 | B | C |
| ATOM | 4344 | CB | LYS | B | 640 | 9.825 | 68.895 | 70.479 | 1.00 | 12.47 | B | C |
| ATOM | 4345 | CG | LYS | B | 640 | 8.486 | 68.943 | 69.785 | 1.00 | 9.84 | B | C |
| ATOM | 4346 | CD | LYS | B | 640 | 8.242 | 67.655 | 69.062 | 1.00 | 6.55 | B | C |
| ATOM | 4347 | CE | LYS | B | 640 | 6.952 | 67.693 | 68.276 | 1.00 | 6.86 | B | C |
| ATOM | 4348 | NZ | LYS | B | 640 | 6.978 | 66.604 | 67.268 | 1.00 | 11.59 | B | N |
| ATOM | 4349 | C | LYS | B | 640 | 11.214 | 69.764 | 72.353 | 1.00 | 14.23 | B | C |
| ATOM | 4350 | O | LYS | B | 640 | 10.973 | 69.128 | 73.380 | 1.00 | 13.49 | B | O |
| ATOM | 4351 | N | GLY | B | 641 | 12.439 | 70.169 | 72.020 | 1.00 | 13.29 | B | N |
| ATOM | 4352 | CA | GLY | B | 641 | 13.568 | 69.909 | 72.897 | 1.00 | 10.24 | B | C |
| ATOM | 4353 | C | GLY | B | 641 | 14.611 | 68.891 | 72.453 | 1.00 | 12.70 | B | C |
| ATOM | 4354 | O | GLY | B | 641 | 15.514 | 68.581 | 73.226 | 1.00 | 10.94 | B | O |
| ATOM | 4355 | N | LEU | B | 642 | 14.509 | 68.358 | 71.236 | 1.00 | 12.11 | B | N |
| ATOM | 4356 | CA | LEU | B | 642 | 15.495 | 67.381 | 70.780 | 1.00 | 10.14 | B | C |
| ATOM | 4357 | CB | LEU | B | 642 | 15.087 | 66.762 | 69.437 | 1.00 | 10.37 | B | C |
| ATOM | 4358 | CG | LEU | B | 642 | 13.765 | 66.008 | 69.174 | 1.00 | 14.55 | B | C |
| ATOM | 4359 | CD1 | LEU | B | 642 | 14.099 | 64.660 | 68.576 | 1.00 | 10.99 | B | C |
| ATOM | 4360 | CD2 | LEU | B | 642 | 12.918 | 65.836 | 70.413 | 1.00 | 13.34 | B | C |
| ATOM | 4361 | C | LEU | B | 642 | 16.850 | 68.082 | 70.640 | 1.00 | 12.84 | B | C |
| ATOM | 4362 | O | LEU | B | 642 | 16.910 | 69.284 | 70.391 | 1.00 | 11.72 | B | O |
| ATOM | 4363 | N | MET | B | 643 | 17.936 | 67.329 | 70.801 | 1.00 | 13.17 | B | N |
| ATOM | 4364 | CA | MET | B | 643 | 19.289 | 67.885 | 70.721 | 1.00 | 15.69 | B | C |
| ATOM | 4365 | CB | MET | B | 643 | 20.280 | 66.877 | 71.312 | 1.00 | 18.95 | B | C |
| ATOM | 4366 | CG | MET | B | 643 | 21.201 | 67.452 | 72.372 | 1.00 | 18.72 | B | C |
| ATOM | 4367 | SD | MET | B | 643 | 22.663 | 68.180 | 71.629 | 1.00 | 26.56 | B | S |
| ATOM | 4368 | CE | MET | B | 643 | 23.851 | 67.955 | 72.933 | 1.00 | 20.29 | B | C |
| ATOM | 4369 | C | MET | B | 643 | 19.684 | 68.228 | 69.284 | 1.00 | 15.83 | B | C |
| ATOM | 4370 | O | MET | B | 643 | 20.284 | 67.402 | 68.584 | 1.00 | 13.59 | B | O |
| ATOM | 4371 | N | ILE | B | 644 | 19.388 | 69.456 | 68.863 | 1.00 | 13.00 | B | N |
| ATOM | 4372 | CA | ILE | B | 644 | 19.655 | 69.885 | 67.484 | 1.00 | 14.60 | B | C |
| ATOM | 4373 | CB | ILE | B | 644 | 18.373 | 70.502 | 66.865 | 1.00 | 14.67 | B | C |
| ATOM | 4374 | CG2 | ILE | B | 644 | 18.618 | 70.877 | 65.429 | 1.00 | 16.05 | B | C |
| ATOM | 4375 | CG1 | ILE | B | 644 | 17.197 | 69.538 | 66.996 | 1.00 | 12.24 | B | C |
| ATOM | 4376 | CD1 | ILE | B | 644 | 17.417 | 68.214 | 66.360 | 1.00 | 11.59 | B | C |
| ATOM | 4377 | C | ILE | B | 644 | 20.780 | 70.903 | 67.217 | 1.00 | 15.53 | B | C |
| ATOM | 4378 | O | ILE | B | 644 | 20.971 | 71.853 | 67.984 | 1.00 | 14.32 | B | O |
| ATOM | 4379 | N | SER | B | 645 | 21.509 | 70.704 | 66.119 | 1.00 | 10.52 | B | N |
| ATOM | 4380 | CA | SER | B | 645 | 22.537 | 71.653 | 65.689 | 1.00 | 9.14 | B | C |
| ATOM | 4381 | CB | SER | B | 645 | 23.956 | 71.185 | 66.057 | 1.00 | 7.58 | B | C |
| ATOM | 4382 | OG | SER | B | 645 | 24.399 | 70.081 | 65.291 | 1.00 | 7.89 | B | O |
| ATOM | 4383 | C | SER | B | 645 | 22.380 | 71.840 | 64.171 | 1.00 | 11.56 | B | C |
| ATOM | 4384 | O | SER | B | 645 | 21.779 | 70.999 | 63.491 | 1.00 | 10.53 | B | O |
| ATOM | 4385 | N | LEU | B | 646 | 22.884 | 72.952 | 63.646 | 1.00 | 10.74 | B | N |
| ATOM | 4386 | CA | LEU | B | 646 | 22.773 | 73.232 | 62.224 | 1.00 | 10.28 | B | C |
| ATOM | 4387 | CB | LEU | B | 646 | 22.356 | 74.691 | 61.998 | 1.00 | 7.76 | B | C |
| ATOM | 4388 | CG | LEU | B | 646 | 20.854 | 74.998 | 62.105 | 1.00 | 9.59 | B | C |
| ATOM | 4389 | CD1 | LEU | B | 646 | 20.632 | 76.478 | 61.957 | 1.00 | 3.41 | B | C |
| ATOM | 4390 | CD2 | LEU | B | 646 | 20.069 | 74.232 | 61.046 | 1.00 | 2.50 | B | C |
| ATOM | 4391 | C | LEU | B | 646 | 24.090 | 72.955 | 61.520 | 1.00 | 13.15 | B | C |
| ATOM | 4392 | O | LEU | B | 646 | 25.158 | 73.306 | 62.025 | 1.00 | 13.71 | B | O |
| ATOM | 4393 | N | SER | B | 647 | 24.011 | 72.305 | 60.361 | 1.00 | 14.32 | B | N |
| ATOM | 4394 | CA | SER | B | 647 | 25.201 | 71.992 | 59.586 | 1.00 | 14.78 | B | C |
| ATOM | 4395 | CB | SER | B | 647 | 25.607 | 70.524 | 59.763 | 1.00 | 10.15 | B | C |
| ATOM | 4396 | OG | SER | B | 647 | 24.521 | 69.659 | 59.509 | 1.00 | 12.88 | B | O |
| ATOM | 4397 | C | SER | B | 647 | 25.007 | 72.315 | 58.107 | 1.00 | 14.86 | B | C |
| ATOM | 4398 | O | SER | B | 647 | 23.890 | 72.446 | 57.616 | 1.00 | 12.60 | B | O |
| ATOM | 4399 | N | THR | B | 648 | 26.130 | 72.420 | 57.414 | 1.00 | 15.71 | B | N |
| ATOM | 4400 | CA | THR | B | 648 | 26.190 | 72.784 | 56.008 | 1.00 | 17.11 | B | C |
| ATOM | 4401 | CB | THR | B | 648 | 27.486 | 73.614 | 55.785 | 1.00 | 16.64 | B | C |
| ATOM | 4402 | OG1 | THR | B | 648 | 27.235 | 74.669 | 54.856 | 1.00 | 22.95 | B | O |
| ATOM | 4403 | CG2 | THR | B | 648 | 28.605 | 72.739 | 55.293 | 1.00 | 11.34 | B | C |
| ATOM | 4404 | C | THR | B | 648 | 26.112 | 71.635 | 54.985 | 1.00 | 15.70 | B | C |
| ATOM | 4405 | O | THR | B | 648 | 25.533 | 71.795 | 53.911 | 1.00 | 15.59 | B | O |
| ATOM | 4406 | N | ASP | B | 649 | 26.690 | 70.487 | 55.330 | 1.00 | 15.44 | B | N |
| ATOM | 4407 | CA | ASP | B | 649 | 26.730 | 69.300 | 54.470 | 1.00 | 14.76 | B | C |
| ATOM | 4408 | CB | ASP | B | 649 | 25.341 | 68.936 | 53.956 | 1.00 | 14.36 | B | C |
| ATOM | 4409 | CG | ASP | B | 649 | 25.234 | 67.465 | 53.571 | 1.00 | 17.68 | B | C |
| ATOM | 4410 | OD1 | ASP | B | 649 | 26.225 | 66.725 | 53.765 | 1.00 | 18.01 | B | O |
| ATOM | 4411 | OD2 | ASP | B | 649 | 24.160 | 67.046 | 53.080 | 1.00 | 17.83 | B | O |
| ATOM | 4412 | C | ASP | B | 649 | 27.696 | 69.422 | 53.288 | 1.00 | 16.34 | B | C |
| ATOM | 4413 | O | ASP | B | 649 | 28.767 | 68.819 | 53.304 | 1.00 | 14.11 | B | O |
| ATOM | 4414 | N | ASP | B | 650 | 27.322 | 70.195 | 52.267 | 1.00 | 17.55 | B | N |
| ATOM | 4415 | CA | ASP | B | 650 | 28.168 | 70.399 | 51.084 | 1.00 | 17.26 | B | C |
| ATOM | 4416 | CB | ASP | B | 650 | 27.747 | 69.449 | 49.960 | 1.00 | 20.78 | B | C |
| ATOM | 4417 | CG | ASP | B | 650 | 28.038 | 67.988 | 50.286 | 1.00 | 25.06 | B | C |
| ATOM | 4418 | OD1 | ASP | B | 650 | 27.088 | 67.219 | 50.545 | 1.00 | 27.39 | B | O |
| ATOM | 4419 | OD2 | ASP | B | 650 | 29.224 | 67.601 | 50.281 | 1.00 | 28.96 | B | O |
| ATOM | 4420 | C | ASP | B | 650 | 28.055 | 71.844 | 50.592 | 1.00 | 17.83 | B | C |
| ATOM | 4421 | O | ASP | B | 650 | 27.316 | 72.134 | 49.657 | 1.00 | 17.47 | B | O |
| ATOM | 4422 | N | PRO | B | 651 | 28.801 | 72.768 | 51.216 | 1.00 | 16.40 | B | N |
| ATOM | 4423 | CD | PRO | B | 651 | 29.742 | 72.524 | 52.318 | 1.00 | 16.41 | B | C |
| ATOM | 4424 | CA | PRO | B | 651 | 28.761 | 74.179 | 50.825 | 1.00 | 17.82 | B | C |
| ATOM | 4425 | CB | PRO | B | 651 | 29.918 | 74.812 | 51.606 | 1.00 | 17.55 | B | C |
| ATOM | 4426 | CG | PRO | B | 651 | 30.159 | 73.903 | 52.735 | 1.00 | 17.57 | B | C |
| ATOM | 4427 | C | PRO | B | 651 | 28.899 | 74.414 | 49.325 | 1.00 | 17.17 | B | C |
| ATOM | 4428 | O | PRO | B | 651 | 28.157 | 75.205 | 48.748 | 1.00 | 17.62 | B | O |
| ATOM | 4429 | N | MET | B | 652 | 29.850 | 73.727 | 48.706 | 1.00 | 17.81 | B | N |
| ATOM | 4430 | CA | MET | B | 652 | 30.096 | 73.867 | 47.276 | 1.00 | 22.40 | B | C |
| ATOM | 4431 | CB | MET | B | 652 | 31.162 | 72.868 | 46.824 | 1.00 | 23.42 | B | C |
| ATOM | 4432 | CG | MET | B | 652 | 31.537 | 73.003 | 45.355 | 1.00 | 27.33 | B | C |
| ATOM | 4433 | SD | MET | B | 652 | 32.920 | 71.957 | 44.910 | 1.00 | 30.94 | B | S |
| ATOM | 4434 | CE | MET | B | 652 | 32.128 | 70.358 | 44.793 | 1.00 | 26.12 | B | C |
| ATOM | 4435 | C | MET | B | 652 | 28.840 | 73.675 | 46.433 | 1.00 | 20.64 | B | C |
| ATOM | 4436 | O | MET | B | 652 | 28.633 | 74.375 | 45.444 | 1.00 | 20.79 | B | O |
| ATOM | 4437 | N | GLN | B | 653 | 28.003 | 72.731 | 46.846 | 1.00 | 19.89 | B | N |
| ATOM | 4438 | CA | GLN | B | 653 | 26.772 | 72.410 | 46.143 | 1.00 | 19.12 | B | C |
| ATOM | 4439 | CB | GLN | B | 653 | 26.417 | 70.941 | 46.388 | 1.00 | 20.75 | B | C |
| ATOM | 4440 | CG | GLN | B | 653 | 26.698 | 70.000 | 45.247 | 1.00 | 26.68 | B | C |
| ATOM | 4441 | CD | GLN | B | 653 | 28.062 | 69.365 | 45.370 | 1.00 | 33.92 | B | C |
| ATOM | 4442 | OE1 | GLN | B | 653 | 29.004 | 69.746 | 44.676 | 1.00 | 38.77 | B | O |
| ATOM | 4443 | NE2 | GLN | B | 653 | 28.181 | 68.392 | 46.261 | 1.00 | 37.44 | B | N |
| ATOM | 4444 | C | GLN | B | 653 | 25.549 | 73.249 | 46.515 | 1.00 | 18.89 | B | C |
| ATOM | 4445 | O | GLN | B | 653 | 24.704 | 73.518 | 45.660 | 1.00 | 18.97 | B | O |
| ATOM | 4446 | N | PHE | B | 654 | 25.444 | 73.674 | 47.774 | 1.00 | 16.60 | B | N |
| ATOM | 4447 | CA | PHE | B | 654 | 24.241 | 74.385 | 48.203 | 1.00 | 15.58 | B | C |
| ATOM | 4448 | CB | PHE | B | 654 | 23.561 | 73.597 | 49.327 | 1.00 | 16.41 | B | C |
| ATOM | 4449 | CG | PHE | B | 654 | 23.543 | 72.099 | 49.122 | 1.00 | 16.09 | B | C |
| ATOM | 4450 | CD1 | PHE | B | 654 | 24.303 | 71.267 | 49.933 | 1.00 | 15.22 | B | C |
| ATOM | 4451 | CD2 | PHE | B | 654 | 22.716 | 71.522 | 48.160 | 1.00 | 14.08 | B | C |
| ATOM | 4452 | CE1 | PHE | B | 654 | 24.240 | 69.876 | 49.794 | 1.00 | 18.64 | B | C |
| ATOM | 4453 | CE2 | PHE | B | 654 | 22.645 | 70.132 | 48.012 | 1.00 | 16.69 | B | C |
| ATOM | 4454 | CZ | PHE | B | 654 | 23.409 | 69.307 | 48.832 | 1.00 | 17.09 | B | C |
| ATOM | 4455 | C | PHE | B | 654 | 24.291 | 75.839 | 48.649 | 1.00 | 16.82 | B | C |
| ATOM | 4456 | O | PHE | B | 654 | 23.237 | 76.463 | 48.788 | 1.00 | 15.81 | B | O |
| ATOM | 4457 | N | HIS | B | 655 | 25.476 | 76.394 | 48.869 | 1.00 | 17.55 | B | N |
| ATOM | 4458 | CA | HIS | B | 655 | 25.545 | 77.767 | 49.358 | 1.00 | 21.16 | B | C |
| ATOM | 4459 | CB | HIS | B | 655 | 26.370 | 77.775 | 50.653 | 1.00 | 20.44 | B | C |
| ATOM | 4460 | CG | HIS | B | 655 | 25.902 | 76.757 | 51.653 | 1.00 | 17.42 | B | C |
| ATOM | 4461 | CD2 | HIS | B | 655 | 26.213 | 75.449 | 51.802 | 1.00 | 15.04 | B | C |
| ATOM | 4462 | ND1 | HIS | B | 655 | 24.906 | 77.019 | 52.569 | 1.00 | 17.27 | B | N |
| ATOM | 4463 | CE1 | HIS | B | 655 | 24.622 | 75.915 | 53.236 | 1.00 | 16.09 | B | C |
| ATOM | 4464 | NE2 | HIS | B | 655 | 25.403 | 74.947 | 52.789 | 1.00 | 13.75 | B | N |
| ATOM | 4465 | C | HIS | B | 655 | 26.037 | 78.825 | 48.374 | 1.00 | 22.40 | B | C |
| ATOM | 4466 | O | HIS | B | 655 | 26.837 | 78.534 | 47.486 | 1.00 | 26.49 | B | O |
| ATOM | 4467 | N | PHE | B | 656 | 25.547 | 80.055 | 48.549 | 1.00 | 25.00 | B | N |
| ATOM | 4468 | CA | PHE | B | 656 | 25.883 | 81.190 | 47.679 | 1.00 | 25.44 | B | C |
| ATOM | 4469 | CB | PHE | B | 656 | 24.624 | 81.991 | 47.355 | 1.00 | 22.02 | B | C |
| ATOM | 4470 | CG | PHE | B | 656 | 23.609 | 81.238 | 46.550 | 1.00 | 23.28 | B | C |
| ATOM | 4471 | CD1 | PHE | B | 656 | 22.495 | 80.684 | 47.162 | 1.00 | 23.99 | B | C |
| ATOM | 4472 | CD2 | PHE | B | 656 | 23.754 | 81.096 | 45.170 | 1.00 | 24.93 | B | C |
| ATOM | 4473 | CE1 | PHE | B | 656 | 21.536 | 79.999 | 46.415 | 1.00 | 22.32 | B | C |
| ATOM | 4474 | CE2 | PHE | B | 656 | 22.800 | 80.413 | 44.413 | 1.00 | 20.18 | B | C |
| ATOM | 4475 | CZ | PHE | B | 656 | 21.690 | 79.864 | 45.038 | 1.00 | 22.61 | B | C |
| ATOM | 4476 | C | PHE | B | 656 | 26.921 | 82.183 | 48.208 | 1.00 | 28.36 | B | C |
| ATOM | 4477 | O | PHE | B | 656 | 27.549 | 82.892 | 47.415 | 1.00 | 30.23 | B | O |
| ATOM | 4478 | N | THR | B | 657 | 27.095 | 82.242 | 49.530 | 1.00 | 30.00 | B | N |
| ATOM | 4479 | CA | THR | B | 657 | 28.025 | 83.191 | 50.148 | 1.00 | 28.50 | B | C |
| ATOM | 4480 | CB | THR | B | 657 | 27.410 | 83.817 | 51.402 | 1.00 | 28.03 | B | C |
| ATOM | 4481 | OG1 | THR | B | 657 | 27.693 | 82.981 | 52.531 | 1.00 | 31.65 | B | O |
| ATOM | 4482 | CG2 | THR | B | 657 | 25.903 | 83.949 | 51.250 | 1.00 | 20.79 | B | C |
| ATOM | 4483 | C | THR | B | 657 | 29.346 | 82.578 | 50.557 | 1.00 | 31.49 | B | C |
| ATOM | 4484 | O | THR | B | 657 | 29.574 | 81.382 | 50.338 | 1.00 | 33.75 | B | O |
| ATOM | 4485 | N | LYS | B | 658 | 30.207 | 83.403 | 51.161 | 1.00 | 33.24 | B | N |
| ATOM | 4486 | CA | LYS | B | 658 | 31.531 | 82.963 | 51.618 | 1.00 | 35.43 | B | C |
| ATOM | 4487 | CB | LYS | B | 658 | 32.539 | 84.124 | 51.559 | 1.00 | 40.92 | B | C |
| ATOM | 4488 | CG | LYS | B | 658 | 33.113 | 84.424 | 50.169 | 1.00 | 46.39 | B | C |
| ATOM | 4489 | CD | LYS | B | 658 | 34.420 | 83.651 | 49.890 | 1.00 | 49.00 | B | C |
| ATOM | 4490 | CE | LYS | B | 658 | 34.769 | 83.655 | 48.394 | 1.00 | 46.56 | B | C |
| ATOM | 4491 | NZ | LYS | B | 658 | 34.641 | 82.309 | 47.777 | 1.00 | 43.04 | B | N |
| ATOM | 4492 | C | LYS | B | 658 | 31.478 | 82.431 | 53.049 | 1.00 | 35.45 | B | C |
| ATOM | 4493 | O | LYS | B | 658 | 32.472 | 81.907 | 53.566 | 1.00 | 35.24 | B | O |
| ATOM | 4494 | N | GLU | B | 659 | 30.326 | 82.587 | 53.695 | 1.00 | 33.89 | B | N |
| ATOM | 4495 | CA | GLU | B | 659 | 30.152 | 82.112 | 55.064 | 1.00 | 33.30 | B | C |
| ATOM | 4496 | CB | GLU | B | 659 | 29.985 | 83.301 | 56.017 | 1.00 | 34.06 | B | C |
| ATOM | 4497 | CG | GLU | B | 659 | 31.301 | 84.028 | 56.315 | 1.00 | 39.02 | B | C |
| ATOM | 4498 | CD | GLU | B | 659 | 31.220 | 84.952 | 57.528 | 1.00 | 43.06 | B | C |
| ATOM | 4499 | OE1 | GLU | B | 659 | 31.582 | 84.515 | 58.648 | 1.00 | 45.18 | B | O |
| ATOM | 4500 | OE2 | GLU | B | 659 | 30.795 | 86.118 | 57.359 | 1.00 | 46.98 | B | O |
| ATOM | 4501 | C | GLU | B | 659 | 28.930 | 81.195 | 55.109 | 1.00 | 30.15 | B | C |
| ATOM | 4502 | O | GLU | B | 659 | 27.884 | 81.542 | 55.670 | 1.00 | 28.93 | B | O |
| ATOM | 4503 | N | PRO | B | 660 | 29.050 | 80.006 | 54.491 | 1.00 | 28.87 | B | N |
| ATOM | 4504 | CD | PRO | B | 660 | 30.253 | 79.562 | 53.761 | 1.00 | 25.68 | B | C |
| ATOM | 4505 | CA | PRO | B | 660 | 27.962 | 79.018 | 54.444 | 1.00 | 25.34 | B | C |
| ATOM | 4506 | CB | PRO | B | 660 | 28.587 | 77.793 | 53.766 | 1.00 | 25.14 | B | C |
| ATOM | 4507 | CG | PRO | B | 660 | 30.053 | 78.089 | 53.627 | 1.00 | 28.81 | B | C |
| ATOM | 4508 | C | PRO | B | 660 | 27.319 | 78.672 | 55.785 | 1.00 | 21.34 | B | C |
| ATOM | 4509 | O | PRO | B | 660 | 26.096 | 78.546 | 55.857 | 1.00 | 20.59 | B | O |
| ATOM | 4510 | N | LEU | B | 661 | 28.117 | 78.511 | 56.841 | 1.00 | 18.18 | B | N |
| ATOM | 4511 | CA | LEU | B | 661 | 27.537 | 78.186 | 58.148 | 1.00 | 16.57 | B | C |
| ATOM | 4512 | CB | LEU | B | 661 | 28.625 | 77.961 | 59.203 | 1.00 | 14.44 | B | C |
| ATOM | 4513 | CG | LEU | B | 661 | 28.464 | 76.803 | 60.211 | 1.00 | 15.92 | B | C |
| ATOM | 4514 | CD1 | LEU | B | 661 | 28.853 | 77.289 | 61.592 | 1.00 | 10.09 | B | C |
| ATOM | 4515 | CD2 | LEU | B | 661 | 27.042 | 76.262 | 60.223 | 1.00 | 10.08 | B | C |
| ATOM | 4516 | C | LEU | B | 661 | 26.625 | 79.330 | 58.586 | 1.00 | 15.47 | B | C |
| ATOM | 4517 | O | LEU | B | 661 | 25.500 | 79.102 | 59.034 | 1.00 | 13.12 | B | O |
| ATOM | 4518 | N | MET | B | 662 | 27.110 | 80.560 | 58.443 | 1.00 | 15.29 | B | N |
| ATOM | 4519 | CA | MET | B | 662 | 26.332 | 81.740 | 58.806 | 1.00 | 17.62 | B | C |
| ATOM | 4520 | CB | MET | B | 662 | 27.171 | 83.009 | 58.650 | 1.00 | 19.51 | B | C |
| ATOM | 4521 | CG | MET | B | 662 | 28.384 | 83.066 | 59.582 | 1.00 | 28.07 | B | C |
| ATOM | 4522 | SD | MET | B | 662 | 27.942 | 82.897 | 61.350 | 1.00 | 34.60 | B | S |
| ATOM | 4523 | CE | MET | B | 662 | 26.750 | 84.263 | 61.532 | 1.00 | 29.39 | B | C |
| ATOM | 4524 | C | MET | B | 662 | 25.116 | 81.820 | 57.902 | 1.00 | 16.66 | B | C |
| ATOM | 4525 | O | MET | B | 662 | 24.062 | 82.320 | 58.299 | 1.00 | 19.11 | B | O |
| ATOM | 4526 | N | GLU | B | 663 | 25.261 | 81.324 | 56.680 | 1.00 | 15.14 | B | N |
| ATOM | 4527 | CA | GLU | B | 663 | 24.158 | 81.327 | 55.725 | 1.00 | 13.73 | B | C |
| ATOM | 4528 | CB | GLU | B | 663 | 24.664 | 80.911 | 54.345 | 1.00 | 17.62 | B | C |
| ATOM | 4529 | CG | GLU | B | 663 | 23.801 | 81.377 | 53.185 | 1.00 | 18.10 | B | C |
| ATOM | 4530 | CD | GLU | B | 663 | 24.319 | 80.880 | 51.845 | 1.00 | 20.90 | B | C |
| ATOM | 4531 | OE1 | GLU | B | 663 | 25.557 | 80.897 | 51.654 | 1.00 | 16.85 | B | O |
| ATOM | 4532 | OE2 | GLU | B | 663 | 23.489 | 80.470 | 50.992 | 1.00 | 17.10 | B | O |
| ATOM | 4533 | C | GLU | B | 663 | 23.050 | 80.376 | 56.183 | 1.00 | 14.50 | B | C |
| ATOM | 4534 | O | GLU | B | 663 | 21.862 | 80.713 | 56.108 | 1.00 | 11.65 | B | O |
| ATOM | 4535 | N | GLU | B | 664 | 23.433 | 79.190 | 56.660 | 1.00 | 13.15 | B | N |
| ATOM | 4536 | CA | GLU | B | 664 | 22.450 | 78.216 | 57.138 | 1.00 | 14.96 | B | C |
| ATOM | 4537 | CB | GLU | B | 664 | 23.115 | 76.883 | 57.494 | 1.00 | 13.70 | B | C |
| ATOM | 4538 | CG | GLU | B | 664 | 23.458 | 76.029 | 56.286 | 1.00 | 23.17 | B | C |
| ATOM | 4539 | CD | GLU | B | 664 | 22.417 | 74.970 | 55.978 | 1.00 | 21.69 | B | C |
| ATOM | 4540 | OE1 | GLU | B | 664 | 21.339 | 74.978 | 56.610 | 1.00 | 22.77 | B | O |
| ATOM | 4541 | OE2 | GLU | B | 664 | 22.682 | 74.127 | 55.093 | 1.00 | 27.19 | B | O |
| ATOM | 4542 | C | GLU | B | 664 | 21.712 | 78.740 | 58.358 | 1.00 | 13.65 | B | C |
| ATOM | 4543 | O | GLU | B | 664 | 20.500 | 78.557 | 58.481 | 1.00 | 16.39 | B | O |
| ATOM | 4544 | N | TYR | B | 665 | 22.447 | 79.391 | 59.258 | 1.00 | 12.58 | B | N |
| ATOM | 4545 | CA | TYR | B | 665 | 21.862 | 79.947 | 60.471 | 1.00 | 9.61 | B | C |
| ATOM | 4546 | CB | TYR | B | 665 | 22.968 | 80.457 | 61.410 | 1.00 | 11.30 | B | C |
| ATOM | 4547 | CG | TYR | B | 665 | 23.485 | 79.422 | 62.393 | 1.00 | 12.91 | B | C |
| ATOM | 4548 | CD1 | TYR | B | 665 | 24.468 | 78.508 | 62.022 | 1.00 | 10.84 | B | C |
| ATOM | 4549 | CE1 | TYR | B | 665 | 24.960 | 77.571 | 62.933 | 1.00 | 14.65 | B | C |
| ATOM | 4550 | CD2 | TYR | B | 665 | 23.003 | 79.371 | 63.705 | 1.00 | 14.74 | B | C |
| ATOM | 4551 | CE2 | TYR | B | 665 | 23.493 | 78.434 | 64.627 | 1.00 | 12.85 | B | C |
| ATOM | 4552 | CZ | TYR | B | 665 | 24.471 | 77.541 | 64.233 | 1.00 | 13.50 | B | C |
| ATOM | 4553 | OH | TYR | B | 665 | 24.975 | 76.623 | 65.133 | 1.00 | 14.42 | B | O |
| ATOM | 4554 | C | TYR | B | 665 | 20.914 | 81.087 | 60.128 | 1.00 | 8.91 | B | C |
| ATOM | 4555 | O | TYR | B | 665 | 19.805 | 81.154 | 60.648 | 1.00 | 10.42 | B | O |
| ATOM | 4556 | N | ALA | B | 666 | 21.348 | 81.980 | 59.244 | 1.00 | 8.96 | B | N |
| ATOM | 4557 | CA | ALA | B | 666 | 20.532 | 83.129 | 58.839 | 1.00 | 8.31 | B | C |
| ATOM | 4558 | CB | ALA | B | 666 | 21.308 | 84.003 | 57.880 | 1.00 | 5.62 | B | C |
| ATOM | 4559 | C | ALA | B | 666 | 19.197 | 82.759 | 58.218 | 1.00 | 10.25 | B | C |
| ATOM | 4560 | O | ALA | B | 666 | 18.156 | 83.265 | 58.621 | 1.00 | 9.38 | B | O |
| ATOM | 4561 | N | ILE | B | 667 | 19.212 | 81.873 | 57.231 | 1.00 | 12.79 | B | N |
| ATOM | 4562 | CA | ILE | B | 667 | 17.963 | 81.497 | 56.586 | 1.00 | 15.20 | B | C |
| ATOM | 4563 | CB | ILE | B | 667 | 18.202 | 80.599 | 55.346 | 1.00 | 17.76 | B | C |
| ATOM | 4564 | CG2 | ILE | B | 667 | 19.001 | 79.374 | 55.745 | 1.00 | 24.29 | B | C |
| ATOM | 4565 | CG1 | ILE | B | 667 | 16.856 | 80.193 | 54.733 | 1.00 | 15.74 | B | C |
| ATOM | 4566 | CD1 | ILE | B | 667 | 16.967 | 79.294 | 53.531 | 1.00 | 17.71 | B | C |
| ATOM | 4567 | C | ILE | B | 667 | 17.059 | 80.773 | 57.569 | 1.00 | 15.27 | B | C |
| ATOM | 4568 | O | ILE | B | 667 | 15.845 | 80.987 | 57.582 | 1.00 | 16.57 | B | O |
| ATOM | 4569 | N | ALA | B | 668 | 17.639 | 79.911 | 58.393 | 1.00 | 12.75 | B | N |
| ATOM | 4570 | CA | ALA | B | 668 | 16.837 | 79.202 | 59.378 | 1.00 | 12.93 | B | C |
| ATOM | 4571 | CB | ALA | B | 668 | 17.715 | 78.257 | 60.199 | 1.00 | 12.41 | B | C |
| ATOM | 4572 | C | ALA | B | 668 | 16.150 | 80.218 | 60.292 | 1.00 | 11.34 | B | C |
| ATOM | 4573 | O | ALA | B | 668 | 14.970 | 80.084 | 60.583 | 1.00 | 9.52 | B | O |
| ATOM | 4574 | N | ALA | B | 669 | 16.889 | 81.235 | 60.730 | 1.00 | 11.18 | B | N |
| ATOM | 4575 | CA | ALA | B | 669 | 16.333 | 82.268 | 61.605 | 1.00 | 11.13 | B | C |
| ATOM | 4576 | CB | ALA | B | 669 | 17.441 | 83.201 | 62.094 | 1.00 | 4.37 | B | C |
| ATOM | 4577 | C | ALA | B | 669 | 15.249 | 83.078 | 60.896 | 1.00 | 13.38 | B | C |
| ATOM | 4578 | O | ALA | B | 669 | 14.216 | 83.395 | 61.487 | 1.00 | 14.49 | B | O |
| ATOM | 4579 | N | GLN | B | 670 | 15.486 | 83.406 | 59.627 | 1.00 | 15.46 | B | N |
| ATOM | 4580 | CA | GLN | B | 670 | 14.535 | 84.188 | 58.844 | 1.00 | 15.21 | B | C |
| ATOM | 4581 | CB | GLN | B | 670 | 15.136 | 84.565 | 57.482 | 1.00 | 18.53 | B | C |
| ATOM | 4582 | CG | GLN | B | 670 | 16.514 | 85.214 | 57.533 | 1.00 | 24.15 | B | C |
| ATOM | 4583 | CD | GLN | B | 670 | 16.456 | 86.720 | 57.714 | 1.00 | 26.29 | B | C |
| ATOM | 4584 | OE1 | GLN | B | 670 | 15.449 | 87.263 | 58.177 | 1.00 | 30.69 | B | O |
| ATOM | 4585 | NE2 | GLN | B | 670 | 17.536 | 87.404 | 57.351 | 1.00 | 23.04 | B | N |
| ATOM | 4586 | C | GLN | B | 670 | 13.202 | 83.471 | 58.624 | 1.00 | 16.68 | B | C |
| ATOM | 4587 | O | GLN | B | 670 | 12.148 | 83.998 | 58.990 | 1.00 | 18.16 | B | O |
| ATOM | 4588 | N | VAL | B | 671 | 13.224 | 82.276 | 58.038 | 1.00 | 14.79 | B | N |
| ATOM | 4589 | CA | VAL | B | 671 | 11.959 | 81.583 | 57.797 | 1.00 | 17.02 | B | C |
| ATOM | 4590 | CB | VAL | B | 671 | 12.045 | 80.592 | 56.573 | 1.00 | 18.26 | B | C |
| ATOM | 4591 | CG1 | VAL | B | 671 | 13.371 | 80.737 | 55.866 | 1.00 | 16.33 | B | C |
| ATOM | 4592 | CG2 | VAL | B | 671 | 11.824 | 79.169 | 57.012 | 1.00 | 17.04 | B | C |
| ATOM | 4593 | C | VAL | B | 671 | 11.351 | 80.871 | 59.009 | 1.00 | 16.26 | B | C |
| ATOM | 4594 | O | VAL | B | 671 | 10.132 | 80.761 | 59.110 | 1.00 | 16.79 | B | O |
| ATOM | 4595 | N | PHE | B | 672 | 12.173 | 80.397 | 59.935 | 1.00 | 16.02 | B | N |
| ATOM | 4596 | CA | PHE | B | 672 | 11.622 | 79.731 | 61.112 | 1.00 | 17.75 | B | C |
| ATOM | 4597 | CB | PHE | B | 672 | 12.532 | 78.587 | 61.543 | 1.00 | 18.31 | B | C |
| ATOM | 4598 | CG | PHE | B | 672 | 12.501 | 77.422 | 60.600 | 1.00 | 18.58 | B | C |
| ATOM | 4599 | CD1 | PHE | B | 672 | 11.313 | 76.748 | 60.352 | 1.00 | 18.87 | B | C |
| ATOM | 4600 | CD2 | PHE | B | 672 | 13.646 | 77.027 | 59.924 | 1.00 | 20.38 | B | C |
| ATOM | 4601 | CE1 | PHE | B | 672 | 11.261 | 75.693 | 59.439 | 1.00 | 19.58 | B | C |
| ATOM | 4602 | CE2 | PHE | B | 672 | 13.607 | 75.973 | 59.008 | 1.00 | 21.74 | B | C |
| ATOM | 4603 | CZ | PHE | B | 672 | 12.409 | 75.305 | 58.766 | 1.00 | 20.23 | B | C |
| ATOM | 4604 | C | PHE | B | 672 | 11.376 | 80.692 | 62.274 | 1.00 | 17.41 | B | C |
| ATOM | 4605 | O | PHE | B | 672 | 10.911 | 80.291 | 63.329 | 1.00 | 18.99 | B | O |
| ATOM | 4606 | N | LYS | B | 673 | 11.686 | 81.966 | 62.051 | 1.00 | 18.10 | B | N |
| ATOM | 4607 | CA | LYS | B | 673 | 11.490 | 83.025 | 63.033 | 1.00 | 17.47 | B | C |
| ATOM | 4608 | CB | LYS | B | 673 | 9.996 | 83.326 | 63.188 | 1.00 | 15.36 | B | C |
| ATOM | 4609 | CG | LYS | B | 673 | 9.553 | 84.541 | 62.381 | 1.00 | 22.66 | B | C |
| ATOM | 4610 | CD | LYS | B | 673 | 8.215 | 84.342 | 61.677 | 1.00 | 29.79 | B | C |
| ATOM | 4611 | CE | LYS | B | 673 | 7.886 | 82.859 | 61.446 | 1.00 | 38.43 | B | C |
| ATOM | 4612 | NZ | LYS | B | 673 | 6.557 | 82.622 | 60.768 | 1.00 | 41.35 | B | N |
| ATOM | 4613 | C | LYS | B | 673 | 12.116 | 82.730 | 64.386 | 1.00 | 17.15 | B | C |
| ATOM | 4614 | O | LYS | B | 673 | 11.471 | 82.853 | 65.425 | 1.00 | 15.43 | B | O |
| ATOM | 4615 | N | LEU | B | 674 | 13.392 | 82.358 | 64.355 | 1.00 | 15.98 | B | N |
| ATOM | 4616 | CA | LEU | B | 674 | 14.155 | 82.040 | 65.555 | 1.00 | 13.50 | B | C |
| ATOM | 4617 | CB | LEU | B | 674 | 15.403 | 81.232 | 65.181 | 1.00 | 10.45 | B | C |
| ATOM | 4618 | CG | LEU | B | 674 | 15.355 | 79.706 | 65.109 | 1.00 | 9.69 | B | C |
| ATOM | 4619 | CD1 | LEU | B | 674 | 13.942 | 79.206 | 64.956 | 1.00 | 9.12 | B | C |
| ATOM | 4620 | CD2 | LEU | B | 674 | 16.197 | 79.264 | 63.950 | 1.00 | 13.46 | B | C |
| ATOM | 4621 | C | LEU | B | 674 | 14.595 | 83.300 | 66.289 | 1.00 | 11.96 | B | C |
| ATOM | 4622 | O | LEU | B | 674 | 14.950 | 84.290 | 65.664 | 1.00 | 14.70 | B | O |
| ATOM | 4623 | N | SER | B | 675 | 14.569 | 83.256 | 67.617 | 1.00 | 11.16 | B | N |
| ATOM | 4624 | CA | SER | B | 675 | 15.007 | 84.381 | 68.440 | 1.00 | 11.94 | B | C |
| ATOM | 4625 | CB | SER | B | 675 | 14.374 | 84.298 | 69.830 | 1.00 | 11.00 | B | C |
| ATOM | 4626 | OG | SER | B | 675 | 14.945 | 83.229 | 70.570 | 1.00 | 12.19 | B | O |
| ATOM | 4627 | C | SER | B | 675 | 16.521 | 84.242 | 68.571 | 1.00 | 12.19 | B | C |
| ATOM | 4628 | O | SER | B | 675 | 17.083 | 83.184 | 68.257 | 1.00 | 9.51 | B | O |
| ATOM | 4629 | N | THR | B | 676 | 17.192 | 85.288 | 69.033 | 1.00 | 12.55 | B | N |
| ATOM | 4630 | CA | THR | B | 676 | 18.633 | 85.191 | 69.180 | 1.00 | 14.91 | B | C |
| ATOM | 4631 | CB | THR | B | 676 | 19.285 | 86.581 | 69.419 | 1.00 | 17.34 | B | C |
| ATOM | 4632 | OG1 | THR | B | 676 | 20.158 | 86.519 | 70.550 | 1.00 | 21.91 | B | O |
| ATOM | 4633 | CG2 | THR | B | 676 | 18.228 | 87.645 | 69.639 | 1.00 | 19.67 | B | C |
| ATOM | 4634 | C | THR | B | 676 | 18.976 | 84.212 | 70.308 | 1.00 | 15.09 | B | C |
| ATOM | 4635 | O | THR | B | 676 | 20.088 | 83.692 | 70.366 | 1.00 | 18.90 | B | O |
| ATOM | 4636 | N | CYS | B | 677 | 18.021 | 83.934 | 71.193 | 1.00 | 14.37 | B | N |
| ATOM | 4637 | CA | CYS | B | 677 | 18.279 | 82.969 | 72.259 | 1.00 | 13.52 | B | C |
| ATOM | 4638 | CB | CYS | B | 677 | 17.238 | 83.073 | 73.379 | 1.00 | 14.48 | B | C |
| ATOM | 4639 | SG | CYS | B | 677 | 17.572 | 81.989 | 74.800 | 1.00 | 11.60 | B | S |
| ATOM | 4640 | C | CYS | B | 677 | 18.210 | 81.584 | 71.630 | 1.00 | 12.03 | B | C |
| ATOM | 4641 | O | CYS | B | 677 | 18.992 | 80.699 | 71.973 | 1.00 | 11.28 | B | O |
| ATOM | 4642 | N | ASP | B | 678 | 17.259 | 81.404 | 70.715 | 1.00 | 12.53 | B | N |
| ATOM | 4643 | CA | ASP | B | 678 | 17.083 | 80.140 | 69.999 | 1.00 | 11.91 | B | C |
| ATOM | 4644 | CB | ASP | B | 678 | 15.916 | 80.232 | 69.012 | 1.00 | 14.76 | B | C |
| ATOM | 4645 | CG | ASP | B | 678 | 14.567 | 80.350 | 69.696 | 1.00 | 18.02 | B | C |
| ATOM | 4646 | OD1 | ASP | B | 678 | 14.421 | 79.833 | 70.826 | 1.00 | 20.44 | B | O |
| ATOM | 4647 | OD2 | ASP | B | 678 | 13.649 | 80.959 | 69.097 | 1.00 | 16.03 | B | O |
| ATOM | 4648 | C | ASP | B | 678 | 18.341 | 79.826 | 69.200 | 1.00 | 13.58 | B | C |
| ATOM | 4649 | O | ASP | B | 678 | 18.796 | 78.686 | 69.164 | 1.00 | 13.43 | B | O |
| ATOM | 4650 | N | MET | B | 679 | 18.895 | 80.849 | 68.557 | 1.00 | 11.04 | B | N |
| ATOM | 4651 | CA | MET | B | 679 | 20.087 | 80.692 | 67.738 | 1.00 | 11.40 | B | C |
| ATOM | 4652 | CB | MET | B | 679 | 20.385 | 81.991 | 66.990 | 1.00 | 14.98 | B | C |
| ATOM | 4653 | CG | MET | B | 679 | 19.342 | 82.387 | 65.971 | 1.00 | 19.47 | B | C |
| ATOM | 4654 | SD | MET | B | 679 | 19.945 | 83.681 | 64.882 | 1.00 | 27.62 | B | S |
| ATOM | 4655 | CE | MET | B | 679 | 19.316 | 85.122 | 65.666 | 1.00 | 25.58 | B | C |
| ATOM | 4656 | C | MET | B | 679 | 21.297 | 80.322 | 68.565 | 1.00 | 12.69 | B | C |
| ATOM | 4657 | O | MET | B | 679 | 22.098 | 79.475 | 68.176 | 1.00 | 13.24 | B | O |
| ATOM | 4658 | N | CYS | B | 680 | 21.447 | 80.982 | 69.706 | 1.00 | 15.78 | B | N |
| ATOM | 4659 | CA | CYS | B | 680 | 22.582 | 80.718 | 70.569 | 1.00 | 13.73 | B | C |
| ATOM | 4660 | CB | CYS | B | 680 | 22.697 | 81.805 | 71.628 | 1.00 | 14.98 | B | C |
| ATOM | 4661 | SG | CYS | B | 680 | 23.185 | 83.409 | 70.937 | 1.00 | 22.11 | B | S |
| ATOM | 4662 | C | CYS | B | 680 | 22.459 | 79.348 | 71.214 | 1.00 | 14.36 | B | C |
| ATOM | 4663 | O | CYS | B | 680 | 23.468 | 78.732 | 71.562 | 1.00 | 16.43 | B | O |
| ATOM | 4664 | N | GLU | B | 681 | 21.233 | 78.856 | 71.371 | 1.00 | 12.11 | B | N |
| ATOM | 4665 | CA | GLU | B | 681 | 21.061 | 77.533 | 71.959 | 1.00 | 12.50 | B | C |
| ATOM | 4666 | CB | GLU | B | 681 | 19.597 | 77.267 | 72.342 | 1.00 | 10.61 | B | C |
| ATOM | 4667 | CG | GLU | B | 681 | 19.387 | 75.890 | 72.961 | 1.00 | 14.34 | B | C |
| ATOM | 4668 | CD | GLU | B | 681 | 17.959 | 75.619 | 73.441 | 1.00 | 16.93 | B | C |
| ATOM | 4669 | OE1 | GLU | B | 681 | 16.996 | 76.219 | 72.908 | 1.00 | 18.73 | B | O |
| ATOM | 4670 | OE2 | GLU | B | 681 | 17.804 | 74.783 | 74.357 | 1.00 | 17.10 | B | O |
| ATOM | 4671 | C | GLU | B | 681 | 21.526 | 76.501 | 70.942 | 1.00 | 13.28 | B | C |
| ATOM | 4672 | O | GLU | B | 681 | 22.130 | 75.492 | 71.306 | 1.00 | 16.21 | B | O |
| ATOM | 4673 | N | VAL | B | 682 | 21.255 | 76.746 | 69.663 | 1.00 | 11.92 | B | N |
| ATOM | 4674 | CA | VAL | B | 682 | 21.689 | 75.807 | 68.630 | 1.00 | 8.73 | B | C |
| ATOM | 4675 | CB | VAL | B | 682 | 21.093 | 76.156 | 67.242 | 1.00 | 10.35 | B | C |
| ATOM | 4676 | CG1 | VAL | B | 682 | 21.808 | 75.362 | 66.152 | 1.00 | 7.24 | B | C |
| ATOM | 4677 | CG2 | VAL | B | 682 | 19.598 | 75.852 | 67.226 | 1.00 | 4.43 | B | C |
| ATOM | 4678 | C | VAL | B | 682 | 23.216 | 75.822 | 68.547 | 1.00 | 6.45 | B | C |
| ATOM | 4679 | O | VAL | B | 682 | 23.843 | 74.785 | 68.365 | 1.00 | 7.19 | B | O |
| ATOM | 4680 | N | ALA | B | 683 | 23.809 | 77.002 | 68.686 | 1.00 | 4.83 | B | N |
| ATOM | 4681 | CA | ALA | B | 683 | 25.260 | 77.127 | 68.648 | 1.00 | 3.63 | B | C |
| ATOM | 4682 | CB | ALA | B | 683 | 25.655 | 78.578 | 68.776 | 1.00 | 3.93 | B | C |
| ATOM | 4683 | C | ALA | B | 683 | 25.885 | 76.317 | 69.775 | 1.00 | 6.18 | B | C |
| ATOM | 4684 | O | ALA | B | 683 | 26.848 | 75.585 | 69.564 | 1.00 | 9.07 | B | O |
| ATOM | 4685 | N | ARG | B | 684 | 25.333 | 76.444 | 70.979 | 1.00 | 11.08 | B | N |
| ATOM | 4686 | CA | ARG | B | 684 | 25.849 | 75.704 | 72.132 | 1.00 | 11.91 | B | C |
| ATOM | 4687 | CB | ARG | B | 684 | 25.047 | 76.046 | 73.383 | 1.00 | 11.38 | B | C |
| ATOM | 4688 | CG | ARG | B | 684 | 25.516 | 75.329 | 74.629 | 1.00 | 14.28 | B | C |
| ATOM | 4689 | CD | ARG | B | 684 | 24.977 | 75.993 | 75.899 | 1.00 | 16.61 | B | C |
| ATOM | 4690 | NE | ARG | B | 684 | 25.573 | 75.411 | 77.097 | 1.00 | 15.00 | B | N |
| ATOM | 4691 | CZ | ARG | B | 684 | 25.141 | 74.296 | 77.679 | 1.00 | 14.02 | B | C |
| ATOM | 4692 | NH1 | ARG | B | 684 | 24.102 | 73.639 | 77.176 | 1.00 | 12.75 | B | N |
| ATOM | 4693 | NH2 | ARG | B | 684 | 25.765 | 73.827 | 78.751 | 1.00 | 10.89 | B | N |
| ATOM | 4694 | C | ARG | B | 684 | 25.767 | 74.205 | 71.856 | 1.00 | 14.34 | B | C |
| ATOM | 4695 | O | ARG | B | 684 | 26.737 | 73.472 | 72.067 | 1.00 | 17.67 | B | O |
| ATOM | 4696 | N | ASN | B | 685 | 24.608 | 73.750 | 71.385 | 1.00 | 12.96 | B | N |
| ATOM | 4697 | CA | ASN | B | 685 | 24.421 | 72.341 | 71.063 | 1.00 | 11.72 | B | C |
| ATOM | 4698 | CB | ASN | B | 685 | 23.064 | 72.128 | 70.397 | 1.00 | 14.10 | B | C |
| ATOM | 4699 | CG | ASN | B | 685 | 21.917 | 72.164 | 71.383 | 1.00 | 15.34 | B | C |
| ATOM | 4700 | OD1 | ASN | B | 685 | 22.114 | 72.429 | 72.568 | 1.00 | 18.14 | B | O |
| ATOM | 4701 | ND2 | ASN | B | 685 | 20.710 | 71.899 | 70.897 | 1.00 | 10.24 | B | N |
| ATOM | 4702 | C | ASN | B | 685 | 25.516 | 71.889 | 70.103 | 1.00 | 12.02 | B | C |
| ATOM | 4703 | O | ASN | B | 685 | 26.128 | 70.844 | 70.291 | 1.00 | 9.86 | B | O |
| ATOM | 4704 | N | SER | B | 686 | 25.756 | 72.684 | 69.067 | 1.00 | 13.62 | B | N |
| ATOM | 4705 | CA | SER | B | 686 | 26.776 | 72.350 | 68.079 | 1.00 | 11.49 | B | C |
| ATOM | 4706 | CB | SER | B | 686 | 26.849 | 73.449 | 67.007 | 1.00 | 6.11 | B | C |
| ATOM | 4707 | OG | SER | B | 686 | 27.779 | 74.459 | 67.333 | 1.00 | 7.19 | B | O |
| ATOM | 4708 | C | SER | B | 686 | 28.144 | 72.107 | 68.728 | 1.00 | 11.60 | B | C |
| ATOM | 4709 | O | SER | B | 686 | 28.848 | 71.171 | 68.347 | 1.00 | 9.26 | B | O |
| ATOM | 4710 | N | VAL | B | 687 | 28.518 | 72.922 | 69.716 | 1.00 | 13.22 | B | N |
| ATOM | 4711 | CA | VAL | B | 687 | 29.807 | 72.732 | 70.387 | 1.00 | 11.65 | B | C |
| ATOM | 4712 | CB | VAL | B | 687 | 30.207 | 73.940 | 71.265 | 1.00 | 13.63 | B | C |
| ATOM | 4713 | CG1 | VAL | B | 687 | 31.618 | 73.727 | 71.815 | 1.00 | 10.54 | B | C |
| ATOM | 4714 | CG2 | VAL | B | 687 | 30.155 | 75.226 | 70.458 | 1.00 | 6.57 | B | C |
| ATOM | 4715 | C | VAL | B | 687 | 29.788 | 71.496 | 71.275 | 1.00 | 12.33 | B | C |
| ATOM | 4716 | O | VAL | B | 687 | 30.759 | 70.746 | 71.329 | 1.00 | 15.89 | B | O |
| ATOM | 4717 | N | LEU | B | 688 | 28.684 | 71.279 | 71.976 | 1.00 | 14.08 | B | N |
| ATOM | 4718 | CA | LEU | B | 688 | 28.576 | 70.119 | 72.851 | 1.00 | 13.81 | B | C |
| ATOM | 4719 | CB | LEU | B | 688 | 27.239 | 70.144 | 73.598 | 1.00 | 13.90 | B | C |
| ATOM | 4720 | CG | LEU | B | 688 | 27.070 | 71.205 | 74.688 | 1.00 | 14.45 | B | C |
| ATOM | 4721 | CD1 | LEU | B | 688 | 25.617 | 71.245 | 75.161 | 1.00 | 11.30 | B | C |
| ATOM | 4722 | CD2 | LEU | B | 688 | 27.994 | 70.878 | 75.835 | 1.00 | 10.43 | B | C |
| ATOM | 4723 | C | LEU | B | 688 | 28.680 | 68.820 | 72.055 | 1.00 | 15.57 | B | C |
| ATOM | 4724 | O | LEU | B | 688 | 29.244 | 67.822 | 72.520 | 1.00 | 18.52 | B | O |
| ATOM | 4725 | N | GLN | B | 689 | 28.140 | 68.838 | 70.845 | 1.00 | 15.15 | B | N |
| ATOM | 4726 | CA | GLN | B | 689 | 28.136 | 67.658 | 69.986 | 1.00 | 13.54 | B | C |
| ATOM | 4727 | CB | GLN | B | 689 | 27.009 | 67.793 | 68.959 | 1.00 | 9.01 | B | C |
| ATOM | 4728 | CG | GLN | B | 689 | 27.135 | 66.869 | 67.774 | 1.00 | 7.08 | B | C |
| ATOM | 4729 | CD | GLN | B | 689 | 25.923 | 66.896 | 66.883 | 1.00 | 6.56 | B | C |
| ATOM | 4730 | OE1 | GLN | B | 689 | 25.628 | 65.928 | 66.195 | 1.00 | 7.35 | B | O |
| ATOM | 4731 | NE2 | GLN | B | 689 | 25.213 | 68.010 | 66.888 | 1.00 | 7.19 | B | N |
| ATOM | 4732 | C | GLN | B | 689 | 29.443 | 67.304 | 69.254 | 1.00 | 13.61 | B | C |
| ATOM | 4733 | O | GLN | B | 689 | 29.760 | 66.128 | 69.096 | 1.00 | 10.75 | B | O |
| ATOM | 4734 | N | CYS | B | 690 | 30.199 | 68.308 | 68.822 | 1.00 | 13.16 | B | N |
| ATOM | 4735 | CA | CYS | B | 690 | 31.417 | 68.056 | 68.060 | 1.00 | 16.18 | B | C |
| ATOM | 4736 | CB | CYS | B | 690 | 31.946 | 69.362 | 67.496 | 1.00 | 16.43 | B | C |
| ATOM | 4737 | SG | CYS | B | 690 | 32.581 | 70.435 | 68.744 | 1.00 | 18.43 | B | S |
| ATOM | 4738 | C | CYS | B | 690 | 32.551 | 67.316 | 68.759 | 1.00 | 18.39 | B | C |
| ATOM | 4739 | O | CYS | B | 690 | 32.426 | 66.917 | 69.911 | 1.00 | 22.82 | B | O |
| ATOM | 4740 | N | GLY | B | 691 | 33.663 | 67.141 | 68.043 | 1.00 | 16.97 | B | N |
| ATOM | 4741 | CA | GLY | B | 691 | 34.805 | 66.426 | 68.584 | 1.00 | 16.85 | B | C |
| ATOM | 4742 | C | GLY | B | 691 | 35.950 | 67.289 | 69.087 | 1.00 | 20.13 | B | C |
| ATOM | 4743 | O | GLY | B | 691 | 37.046 | 66.780 | 69.356 | 1.00 | 21.69 | B | O |
| ATOM | 4744 | N | ILE | B | 692 | 35.717 | 68.591 | 69.214 | 1.00 | 16.79 | B | N |
| ATOM | 4745 | CA | ILE | B | 692 | 36.747 | 69.491 | 69.712 | 1.00 | 16.10 | B | C |
| ATOM | 4746 | CB | ILE | B | 692 | 36.181 | 70.914 | 69.871 | 1.00 | 17.84 | B | C |
| ATOM | 4747 | CG2 | ILE | B | 692 | 37.195 | 71.825 | 70.570 | 1.00 | 18.28 | B | C |
| ATOM | 4748 | CG1 | ILE | B | 692 | 35.825 | 71.472 | 68.491 | 1.00 | 18.11 | B | C |
| ATOM | 4749 | CD1 | ILE | B | 692 | 35.573 | 72.983 | 68.470 | 1.00 | 18.41 | B | C |
| ATOM | 4750 | C | ILE | B | 692 | 37.242 | 68.972 | 71.064 | 1.00 | 15.85 | B | C |
| ATOM | 4751 | O | ILE | B | 692 | 36.531 | 68.236 | 71.748 | 1.00 | 15.56 | B | O |
| ATOM | 4752 | N | SER | B | 693 | 38.457 | 69.350 | 71.454 | 1.00 | 16.38 | B | N |
| ATOM | 4753 | CA | SER | B | 693 | 39.012 | 68.889 | 72.720 | 1.00 | 16.99 | B | C |
| ATOM | 4754 | CB | SER | B | 693 | 40.508 | 69.188 | 72.773 | 1.00 | 17.14 | B | C |
| ATOM | 4755 | OG | SER | B | 693 | 40.754 | 70.578 | 72.898 | 1.00 | 20.20 | B | O |
| ATOM | 4756 | C | SER | B | 693 | 38.321 | 69.490 | 73.942 | 1.00 | 19.19 | B | C |
| ATOM | 4757 | O | SER | B | 693 | 37.697 | 70.551 | 73.863 | 1.00 | 18.27 | B | O |
| ATOM | 4758 | N | HIS | B | 694 | 38.444 | 68.797 | 75.073 | 1.00 | 22.32 | B | N |
| ATOM | 4759 | CA | HIS | B | 694 | 37.847 | 69.223 | 76.330 | 1.00 | 23.38 | B | C |
| ATOM | 4760 | CB | HIS | B | 694 | 38.157 | 68.213 | 77.430 | 1.00 | 24.30 | B | C |
| ATOM | 4761 | CG | HIS | B | 694 | 37.666 | 68.629 | 78.784 | 1.00 | 29.51 | B | C |
| ATOM | 4762 | CD2 | HIS | B | 694 | 36.436 | 68.553 | 79.346 | 1.00 | 28.54 | B | C |
| ATOM | 4763 | ND1 | HIS | B | 694 | 38.483 | 69.218 | 79.727 | 1.00 | 27.36 | B | N |
| ATOM | 4764 | CE1 | HIS | B | 694 | 37.777 | 69.488 | 80.810 | 1.00 | 26.36 | B | C |
| ATOM | 4765 | NE2 | HIS | B | 694 | 36.532 | 69.095 | 80.606 | 1.00 | 27.06 | B | N |
| ATOM | 4766 | C | HIS | B | 694 | 38.343 | 70.593 | 76.764 | 1.00 | 25.61 | B | C |
| ATOM | 4767 | O | HIS | B | 694 | 37.551 | 71.476 | 77.094 | 1.00 | 28.73 | B | O |
| ATOM | 4768 | N | GLU | B | 695 | 39.656 | 70.771 | 76.770 | 1.00 | 28.09 | B | N |
| ATOM | 4769 | CA | GLU | B | 695 | 40.229 | 72.044 | 77.175 | 1.00 | 30.74 | B | C |
| ATOM | 4770 | CB | GLU | B | 695 | 41.751 | 72.030 | 76.992 | 1.00 | 35.92 | B | C |
| ATOM | 4771 | CG | GLU | B | 695 | 42.451 | 73.294 | 77.494 | 1.00 | 46.52 | B | C |
| ATOM | 4772 | CD | GLU | B | 695 | 43.540 | 73.795 | 76.545 | 1.00 | 54.21 | B | C |
| ATOM | 4773 | OE1 | GLU | B | 695 | 44.716 | 73.401 | 76.726 | 1.00 | 56.64 | B | O |
| ATOM | 4774 | OE2 | GLU | B | 695 | 43.221 | 74.582 | 75.619 | 1.00 | 56.54 | B | O |
| ATOM | 4775 | C | GLU | B | 695 | 39.616 | 73.186 | 76.378 | 1.00 | 29.45 | B | C |
| ATOM | 4776 | O | GLU | B | 695 | 39.207 | 74.196 | 76.945 | 1.00 | 31.84 | B | O |
| ATOM | 4777 | N | GLU | B | 696 | 39.539 | 73.025 | 75.062 | 1.00 | 27.85 | B | N |
| ATOM | 4778 | CA | GLU | B | 696 | 38.978 | 74.070 | 74.215 | 1.00 | 25.70 | B | C |
| ATOM | 4779 | CB | GLU | B | 696 | 39.225 | 73.744 | 72.753 | 1.00 | 29.87 | B | C |
| ATOM | 4780 | CG | GLU | B | 696 | 40.373 | 74.519 | 72.149 | 1.00 | 35.94 | B | C |
| ATOM | 4781 | CD | GLU | B | 696 | 41.000 | 73.769 | 70.999 | 1.00 | 38.15 | B | C |
| ATOM | 4782 | OE1 | GLU | B | 696 | 41.010 | 74.315 | 69.870 | 1.00 | 38.61 | B | O |
| ATOM | 4783 | OE2 | GLU | B | 696 | 41.472 | 72.630 | 71.231 | 1.00 | 37.52 | B | O |
| ATOM | 4784 | C | GLU | B | 696 | 37.491 | 74.271 | 74.436 | 1.00 | 22.01 | B | C |
| ATOM | 4785 | O | GLU | B | 696 | 37.017 | 75.401 | 74.496 | 1.00 | 19.70 | B | O |
| ATOM | 4786 | N | LYS | B | 697 | 36.751 | 73.173 | 74.546 | 1.00 | 21.60 | B | N |
| ATOM | 4787 | CA | LYS | B | 697 | 35.312 | 73.261 | 74.774 | 1.00 | 20.81 | B | C |
| ATOM | 4788 | CB | LYS | B | 697 | 34.707 | 71.863 | 74.914 | 1.00 | 16.83 | B | C |
| ATOM | 4789 | CG | LYS | B | 697 | 34.269 | 71.240 | 73.593 | 1.00 | 18.01 | B | C |
| ATOM | 4790 | CD | LYS | B | 697 | 33.376 | 70.022 | 73.808 | 1.00 | 11.14 | B | C |
| ATOM | 4791 | CE | LYS | B | 697 | 33.156 | 69.253 | 72.518 | 1.00 | 12.32 | B | C |
| ATOM | 4792 | NZ | LYS | B | 697 | 32.209 | 68.119 | 72.700 | 1.00 | 14.81 | B | N |
| ATOM | 4793 | C | LYS | B | 697 | 35.053 | 74.070 | 76.044 | 1.00 | 22.59 | B | C |
| ATOM | 4794 | O | LYS | B | 697 | 34.205 | 74.961 | 76.059 | 1.00 | 24.37 | B | O |
| ATOM | 4795 | N | ALA | B | 698 | 35.795 | 73.762 | 77.106 | 1.00 | 23.81 | B | N |
| ATOM | 4796 | CA | ALA | B | 698 | 35.650 | 74.463 | 78.377 | 1.00 | 23.60 | B | C |
| ATOM | 4797 | CB | ALA | B | 698 | 36.647 | 73.915 | 79.387 | 1.00 | 23.35 | B | C |
| ATOM | 4798 | C | ALA | B | 698 | 35.864 | 75.962 | 78.199 | 1.00 | 25.31 | B | C |
| ATOM | 4799 | O | ALA | B | 698 | 35.257 | 76.778 | 78.896 | 1.00 | 26.97 | B | O |
| ATOM | 4800 | N | LYS | B | 699 | 36.727 | 76.321 | 77.255 | 1.00 | 25.43 | B | N |
| ATOM | 4801 | CA | LYS | B | 699 | 37.038 | 77.716 | 76.980 | 1.00 | 22.86 | B | C |
| ATOM | 4802 | CB | LYS | B | 699 | 38.374 | 77.802 | 76.235 | 1.00 | 25.54 | B | C |
| ATOM | 4803 | CG | LYS | B | 699 | 38.593 | 79.088 | 75.451 | 1.00 | 32.06 | B | C |
| ATOM | 4804 | CD | LYS | B | 699 | 39.914 | 79.048 | 74.676 | 1.00 | 36.21 | B | C |
| ATOM | 4805 | CE | LYS | B | 699 | 39.937 | 80.067 | 73.535 | 1.00 | 35.67 | B | C |
| ATOM | 4806 | NZ | LYS | B | 699 | 40.193 | 81.459 | 74.010 | 1.00 | 33.57 | B | N |
| ATOM | 4807 | C | LYS | B | 699 | 35.939 | 78.418 | 76.185 | 1.00 | 22.98 | B | C |
| ATOM | 4808 | O | LYS | B | 699 | 35.805 | 79.642 | 76.257 | 1.00 | 22.50 | B | O |
| ATOM | 4809 | N | PHE | B | 700 | 35.152 | 77.652 | 75.432 | 1.00 | 19.48 | B | N |
| ATOM | 4810 | CA | PHE | B | 700 | 34.071 | 78.238 | 74.634 | 1.00 | 18.17 | B | C |
| ATOM | 4811 | CB | PHE | B | 700 | 33.850 | 77.464 | 73.321 | 1.00 | 16.38 | B | C |
| ATOM | 4812 | CG | PHE | B | 700 | 35.063 | 77.366 | 72.442 | 1.00 | 12.83 | B | C |
| ATOM | 4813 | CD1 | PHE | B | 700 | 36.022 | 78.367 | 72.427 | 1.00 | 14.56 | B | C |
| ATOM | 4814 | CD2 | PHE | B | 700 | 35.245 | 76.256 | 71.627 | 1.00 | 13.66 | B | C |
| ATOM | 4815 | CE1 | PHE | B | 700 | 37.148 | 78.262 | 71.618 | 1.00 | 11.37 | B | C |
| ATOM | 4816 | CE2 | PHE | B | 700 | 36.366 | 76.143 | 70.817 | 1.00 | 11.29 | B | C |
| ATOM | 4817 | CZ | PHE | B | 700 | 37.319 | 77.151 | 70.815 | 1.00 | 10.09 | B | C |
| ATOM | 4818 | C | PHE | B | 700 | 32.752 | 78.234 | 75.385 | 1.00 | 17.60 | B | C |
| ATOM | 4819 | O | PHE | B | 700 | 31.968 | 79.170 | 75.277 | 1.00 | 13.64 | B | O |
| ATOM | 4820 | N | LEU | B | 701 | 32.513 | 77.161 | 76.134 | 1.00 | 20.08 | B | N |
| ATOM | 4821 | CA | LEU | B | 701 | 31.265 | 76.987 | 76.874 | 1.00 | 22.25 | B | C |
| ATOM | 4822 | CB | LEU | B | 701 | 30.736 | 75.564 | 76.650 | 1.00 | 18.42 | B | C |
| ATOM | 4823 | CG | LEU | B | 701 | 30.544 | 75.057 | 75.221 | 1.00 | 16.66 | B | C |
| ATOM | 4824 | CD1 | LEU | B | 701 | 30.041 | 73.630 | 75.261 | 1.00 | 15.56 | B | C |
| ATOM | 4825 | CD2 | LEU | B | 701 | 29.548 | 75.938 | 74.489 | 1.00 | 15.39 | B | C |
| ATOM | 4826 | C | LEU | B | 701 | 31.305 | 77.247 | 78.382 | 1.00 | 24.02 | B | C |
| ATOM | 4827 | O | LEU | B | 701 | 30.255 | 77.412 | 79.006 | 1.00 | 26.88 | B | O |
| ATOM | 4828 | N | GLY | B | 702 | 32.501 | 77.272 | 78.963 | 1.00 | 25.50 | B | N |
| ATOM | 4829 | CA | GLY | B | 702 | 32.640 | 77.468 | 80.399 | 1.00 | 26.46 | B | C |
| ATOM | 4830 | C | GLY | B | 702 | 33.234 | 76.194 | 80.976 | 1.00 | 26.94 | B | C |
| ATOM | 4831 | O | GLY | B | 702 | 33.165 | 75.149 | 80.333 | 1.00 | 28.74 | B | O |
| ATOM | 4832 | N | ASN | B | 703 | 33.796 | 76.251 | 82.179 | 1.00 | 26.21 | B | N |
| ATOM | 4833 | CA | ASN | B | 703 | 34.423 | 75.068 | 82.773 | 1.00 | 28.67 | B | C |
| ATOM | 4834 | CB | ASN | B | 703 | 35.311 | 75.490 | 83.947 | 1.00 | 31.89 | B | C |
| ATOM | 4835 | CG | ASN | B | 703 | 36.542 | 76.253 | 83.498 | 1.00 | 34.81 | B | C |
| ATOM | 4836 | OD1 | ASN | B | 703 | 37.438 | 75.695 | 82.866 | 1.00 | 37.46 | B | O |
| ATOM | 4837 | ND2 | ASN | B | 703 | 36.588 | 77.537 | 83.820 | 1.00 | 37.95 | B | N |
| ATOM | 4838 | C | ASN | B | 703 | 33.518 | 73.919 | 83.225 | 1.00 | 26.51 | B | C |
| ATOM | 4839 | O | ASN | B | 703 | 33.990 | 72.800 | 83.412 | 1.00 | 26.60 | B | O |
| ATOM | 4840 | N | ASN | B | 704 | 32.228 | 74.180 | 83.385 | 1.00 | 25.55 | B | N |
| ATOM | 4841 | CA | ASN | B | 704 | 31.297 | 73.152 | 83.845 | 1.00 | 23.32 | B | C |
| ATOM | 4842 | CB | ASN | B | 704 | 30.433 | 73.715 | 84.970 | 1.00 | 30.28 | B | C |
| ATOM | 4843 | CG | ASN | B | 704 | 30.794 | 73.149 | 86.322 | 1.00 | 35.16 | B | C |
| ATOM | 4844 | OD1 | ASN | B | 704 | 30.171 | 72.192 | 86.796 | 1.00 | 36.12 | B | O |
| ATOM | 4845 | ND2 | ASN | B | 704 | 31.806 | 73.739 | 86.958 | 1.00 | 35.95 | B | N |
| ATOM | 4846 | C | ASN | B | 704 | 30.380 | 72.604 | 82.768 | 1.00 | 21.18 | B | C |
| ATOM | 4847 | O | ASN | B | 704 | 29.406 | 71.920 | 83.071 | 1.00 | 19.39 | B | O |
| ATOM | 4848 | N | TYR | B | 705 | 30.697 | 72.896 | 81.514 | 1.00 | 21.00 | B | N |
| ATOM | 4849 | CA | TYR | B | 705 | 29.878 | 72.463 | 80.386 | 1.00 | 21.77 | B | C |
| ATOM | 4850 | CB | TYR | B | 705 | 30.605 | 72.791 | 79.068 | 1.00 | 21.60 | B | C |
| ATOM | 4851 | CG | TYR | B | 705 | 31.641 | 71.771 | 78.634 | 1.00 | 20.44 | B | C |
| ATOM | 4852 | CD1 | TYR | B | 705 | 32.986 | 71.931 | 78.965 | 1.00 | 17.26 | B | C |
| ATOM | 4853 | CE1 | TYR | B | 705 | 33.937 | 70.996 | 78.568 | 1.00 | 18.81 | B | C |
| ATOM | 4854 | CD2 | TYR | B | 705 | 31.271 | 70.646 | 77.891 | 1.00 | 18.37 | B | C |
| ATOM | 4855 | CE2 | TYR | B | 705 | 32.210 | 69.708 | 77.492 | 1.00 | 18.96 | B | C |
| ATOM | 4856 | CZ | TYR | B | 705 | 33.542 | 69.885 | 77.830 | 1.00 | 20.22 | B | C |
| ATOM | 4857 | OH | TYR | B | 705 | 34.471 | 68.957 | 77.411 | 1.00 | 20.37 | B | O |
| ATOM | 4858 | C | TYR | B | 705 | 29.419 | 70.998 | 80.396 | 1.00 | 21.84 | B | C |
| ATOM | 4859 | O | TYR | B | 705 | 28.359 | 70.681 | 79.851 | 1.00 | 21.61 | B | O |
| ATOM | 4860 | N | LEU | B | 706 | 30.189 | 70.109 | 81.018 | 1.00 | 20.68 | B | N |
| ATOM | 4861 | CA | LEU | B | 706 | 29.811 | 68.697 | 81.049 | 1.00 | 22.15 | B | C |
| ATOM | 4862 | CB | LEU | B | 706 | 31.019 | 67.830 | 81.423 | 1.00 | 19.58 | B | C |
| ATOM | 4863 | CG | LEU | B | 706 | 32.098 | 67.625 | 80.349 | 1.00 | 19.96 | B | C |
| ATOM | 4864 | CD1 | LEU | B | 706 | 33.335 | 67.010 | 80.987 | 1.00 | 15.77 | B | C |
| ATOM | 4865 | CD2 | LEU | B | 706 | 31.573 | 66.730 | 79.229 | 1.00 | 16.24 | B | C |
| ATOM | 4866 | C | LEU | B | 706 | 28.646 | 68.409 | 82.001 | 1.00 | 24.50 | B | C |
| ATOM | 4867 | O | LEU | B | 706 | 28.011 | 67.352 | 81.916 | 1.00 | 23.89 | B | O |
| ATOM | 4868 | N | GLU | B | 707 | 28.363 | 69.347 | 82.903 | 1.00 | 25.57 | B | N |
| ATOM | 4869 | CA | GLU | B | 707 | 27.271 | 69.185 | 83.859 | 1.00 | 26.55 | B | C |
| ATOM | 4870 | CB | GLU | B | 707 | 27.498 | 70.090 | 85.072 | 1.00 | 30.85 | B | C |
| ATOM | 4871 | CG | GLU | B | 707 | 28.595 | 69.606 | 86.009 | 1.00 | 36.28 | B | C |
| ATOM | 4872 | CD | GLU | B | 707 | 28.409 | 68.153 | 86.406 | 1.00 | 39.86 | B | C |
| ATOM | 4873 | OE1 | GLU | B | 707 | 29.295 | 67.325 | 86.096 | 1.00 | 40.09 | B | O |
| ATOM | 4874 | OE2 | GLU | B | 707 | 27.372 | 67.838 | 87.028 | 1.00 | 41.58 | B | O |
| ATOM | 4875 | C | GLU | B | 707 | 25.947 | 69.539 | 83.188 | 1.00 | 24.98 | B | C |
| ATOM | 4876 | O | GLU | B | 707 | 25.860 | 70.525 | 82.464 | 1.00 | 24.11 | B | O |
| ATOM | 4877 | N | GLU | B | 708 | 24.917 | 68.739 | 83.438 | 1.00 | 26.11 | B | N |
| ATOM | 4878 | CA | GLU | B | 708 | 23.607 | 68.968 | 82.835 | 1.00 | 27.35 | B | C |
| ATOM | 4879 | CB | GLU | B | 708 | 22.834 | 67.645 | 82.732 | 1.00 | 28.96 | B | C |
| ATOM | 4880 | CG | GLU | B | 708 | 23.704 | 66.406 | 82.855 | 1.00 | 33.98 | B | C |
| ATOM | 4881 | CD | GLU | B | 708 | 23.459 | 65.395 | 81.746 | 1.00 | 34.00 | B | C |
| ATOM | 4882 | OE1 | GLU | B | 708 | 22.383 | 64.770 | 81.742 | 1.00 | 29.84 | B | O |
| ATOM | 4883 | OE2 | GLU | B | 708 | 24.349 | 65.219 | 80.883 | 1.00 | 37.16 | B | O |
| ATOM | 4884 | C | GLU | B | 708 | 22.750 | 69.997 | 83.573 | 1.00 | 25.77 | B | C |
| ATOM | 4885 | O | GLU | B | 708 | 22.800 | 70.098 | 84.796 | 1.00 | 27.13 | B | O |
| ATOM | 4886 | N | GLY | B | 709 | 21.961 | 70.755 | 82.815 | 1.00 | 22.69 | B | N |
| ATOM | 4887 | CA | GLY | B | 709 | 21.090 | 71.753 | 83.406 | 1.00 | 17.91 | B | C |
| ATOM | 4888 | C | GLY | B | 709 | 21.718 | 73.125 | 83.495 | 1.00 | 17.34 | B | C |
| ATOM | 4889 | O | GLY | B | 709 | 22.816 | 73.345 | 82.989 | 1.00 | 21.29 | B | O |
| ATOM | 4890 | N | PRO | B | 710 | 21.044 | 74.078 | 84.146 | 1.00 | 15.70 | B | N |
| ATOM | 4891 | CD | PRO | B | 710 | 19.731 | 73.890 | 84.785 | 1.00 | 14.81 | B | C |
| ATOM | 4892 | CA | PRO | B | 710 | 21.540 | 75.449 | 84.303 | 1.00 | 16.31 | B | C |
| ATOM | 4893 | CB | PRO | B | 710 | 20.506 | 76.100 | 85.220 | 1.00 | 14.34 | B | C |
| ATOM | 4894 | CG | PRO | B | 710 | 19.276 | 75.293 | 85.039 | 1.00 | 13.75 | B | C |
| ATOM | 4895 | C | PRO | B | 710 | 22.942 | 75.536 | 84.896 | 1.00 | 17.37 | B | C |
| ATOM | 4896 | O | PRO | B | 710 | 23.709 | 76.452 | 84.594 | 1.00 | 18.42 | B | O |
| ATOM | 4897 | N | ILE | B | 711 | 23.266 | 74.576 | 85.751 | 1.00 | 18.91 | B | N |
| ATOM | 4898 | CA | ILE | B | 711 | 24.549 | 74.557 | 86.416 | 1.00 | 16.93 | B | C |
| ATOM | 4899 | CB | ILE | B | 711 | 24.603 | 73.393 | 87.424 | 1.00 | 21.01 | B | C |
| ATOM | 4900 | CG2 | ILE | B | 711 | 24.881 | 72.088 | 86.710 | 1.00 | 24.43 | B | C |
| ATOM | 4901 | CG1 | ILE | B | 711 | 25.664 | 73.680 | 88.489 | 1.00 | 24.79 | B | C |
| ATOM | 4902 | CD1 | ILE | B | 711 | 25.486 | 75.022 | 89.204 | 1.00 | 22.52 | B | C |
| ATOM | 4903 | C | ILE | B | 711 | 25.719 | 74.472 | 85.449 | 1.00 | 19.35 | B | C |
| ATOM | 4904 | O | ILE | B | 711 | 26.784 | 75.036 | 85.709 | 1.00 | 20.45 | B | O |
| ATOM | 4905 | N | GLY | B | 712 | 25.518 | 73.789 | 84.324 | 1.00 | 17.57 | B | N |
| ATOM | 4906 | CA | GLY | B | 712 | 26.587 | 73.652 | 83.352 | 1.00 | 16.86 | B | C |
| ATOM | 4907 | C | GLY | B | 712 | 26.680 | 74.747 | 82.298 | 1.00 | 18.45 | B | C |
| ATOM | 4908 | O | GLY | B | 712 | 27.507 | 74.660 | 81.394 | 1.00 | 20.70 | B | O |
| ATOM | 4909 | N | ASN | B | 713 | 25.852 | 75.781 | 82.397 | 1.00 | 17.57 | B | N |
| ATOM | 4910 | CA | ASN | B | 713 | 25.902 | 76.849 | 81.412 | 1.00 | 16.77 | B | C |
| ATOM | 4911 | CB | ASN | B | 713 | 24.509 | 77.134 | 80.853 | 1.00 | 14.33 | B | C |
| ATOM | 4912 | CG | ASN | B | 713 | 24.495 | 78.338 | 79.920 | 1.00 | 15.77 | B | C |
| ATOM | 4913 | OD1 | ASN | B | 713 | 23.745 | 79.300 | 80.127 | 1.00 | 11.46 | B | O |
| ATOM | 4914 | ND2 | ASN | B | 713 | 25.336 | 78.294 | 78.888 | 1.00 | 12.98 | B | N |
| ATOM | 4915 | C | ASN | B | 713 | 26.480 | 78.143 | 81.945 | 1.00 | 18.09 | B | C |
| ATOM | 4916 | O | ASN | B | 713 | 26.059 | 78.638 | 82.987 | 1.00 | 22.38 | B | O |
| ATOM | 4917 | N | ASP | B | 714 | 27.444 | 78.696 | 81.218 | 1.00 | 19.91 | B | N |
| ATOM | 4918 | CA | ASP | B | 714 | 28.058 | 79.962 | 81.596 | 1.00 | 18.70 | B | C |
| ATOM | 4919 | CB | ASP | B | 714 | 29.580 | 79.842 | 81.597 | 1.00 | 19.95 | B | C |
| ATOM | 4920 | CG | ASP | B | 714 | 30.268 | 81.102 | 82.094 | 1.00 | 22.51 | B | C |
| ATOM | 4921 | OD1 | ASP | B | 714 | 29.596 | 82.149 | 82.236 | 1.00 | 22.25 | B | O |
| ATOM | 4922 | OD2 | ASP | B | 714 | 31.493 | 81.044 | 82.340 | 1.00 | 25.68 | B | O |
| ATOM | 4923 | C | ASP | B | 714 | 27.613 | 80.947 | 80.529 | 1.00 | 17.80 | B | C |
| ATOM | 4924 | O | ASP | B | 714 | 28.234 | 81.041 | 79.468 | 1.00 | 19.23 | B | O |
| ATOM | 4925 | N | ILE | B | 715 | 26.531 | 81.669 | 80.805 | 1.00 | 16.42 | B | N |
| ATOM | 4926 | CA | ILE | B | 715 | 25.988 | 82.625 | 79.852 | 1.00 | 15.41 | B | C |
| ATOM | 4927 | CB | ILE | B | 715 | 24.760 | 83.365 | 80.439 | 1.00 | 15.87 | B | C |
| ATOM | 4928 | CG2 | ILE | B | 715 | 25.191 | 84.291 | 81.576 | 1.00 | 15.25 | B | C |
| ATOM | 4929 | CG1 | ILE | B | 715 | 24.047 | 84.150 | 79.334 | 1.00 | 15.22 | B | C |
| ATOM | 4930 | CD1 | ILE | B | 715 | 22.803 | 84.874 | 79.808 | 1.00 | 13.45 | B | C |
| ATOM | 4931 | C | ILE | B | 715 | 27.006 | 83.649 | 79.380 | 1.00 | 17.02 | B | C |
| ATOM | 4932 | O | ILE | B | 715 | 26.869 | 84.212 | 78.302 | 1.00 | 17.67 | B | O |
| ATOM | 4933 | N | ARG | B | 716 | 28.035 | 83.893 | 80.177 | 1.00 | 18.95 | B | N |
| ATOM | 4934 | CA | ARG | B | 716 | 29.043 | 84.869 | 79.791 | 1.00 | 21.15 | B | C |
| ATOM | 4935 | CB | ARG | B | 716 | 30.041 | 85.085 | 80.928 | 1.00 | 24.00 | B | C |
| ATOM | 4936 | CG | ARG | B | 716 | 29.575 | 86.068 | 81.990 | 1.00 | 30.64 | B | C |
| ATOM | 4937 | CD | ARG | B | 716 | 30.530 | 86.117 | 83.174 | 1.00 | 34.42 | B | C |
| ATOM | 4938 | NE | ARG | B | 716 | 30.936 | 84.785 | 83.619 | 1.00 | 39.56 | B | N |
| ATOM | 4939 | CZ | ARG | B | 716 | 31.986 | 84.548 | 84.400 | 1.00 | 41.56 | B | C |
| ATOM | 4940 | NH1 | ARG | B | 716 | 32.740 | 85.555 | 84.824 | 1.00 | 41.49 | B | N |
| ATOM | 4941 | NH2 | ARG | B | 716 | 32.285 | 83.306 | 84.757 | 1.00 | 39.96 | B | N |
| ATOM | 4942 | C | ARG | B | 716 | 29.781 | 84.383 | 78.555 | 1.00 | 22.81 | B | C |
| ATOM | 4943 | O | ARG | B | 716 | 30.399 | 85.168 | 77.832 | 1.00 | 21.83 | B | O |
| ATOM | 4944 | N | LYS | B | 717 | 29.701 | 83.081 | 78.309 | 1.00 | 23.02 | B | N |
| ATOM | 4945 | CA | LYS | B | 717 | 30.384 | 82.479 | 77.174 | 1.00 | 21.63 | B | C |
| ATOM | 4946 | CB | LYS | B | 717 | 31.261 | 81.323 | 77.665 | 1.00 | 22.38 | B | C |
| ATOM | 4947 | CG | LYS | B | 717 | 32.687 | 81.737 | 78.011 | 1.00 | 23.92 | B | C |
| ATOM | 4948 | CD | LYS | B | 717 | 33.332 | 80.726 | 78.937 | 1.00 | 28.98 | B | C |
| ATOM | 4949 | CE | LYS | B | 717 | 34.794 | 81.053 | 79.193 | 1.00 | 31.76 | B | C |
| ATOM | 4950 | NZ | LYS | B | 717 | 35.488 | 79.922 | 79.909 | 1.00 | 33.96 | B | N |
| ATOM | 4951 | C | LYS | B | 717 | 29.457 | 81.987 | 76.064 | 1.00 | 20.24 | B | C |
| ATOM | 4952 | O | LYS | B | 717 | 29.817 | 82.038 | 74.889 | 1.00 | 20.19 | B | O |
| ATOM | 4953 | N | THR | B | 718 | 28.264 | 81.528 | 76.433 | 1.00 | 20.14 | B | N |
| ATOM | 4954 | CA | THR | B | 718 | 27.308 | 81.004 | 75.463 | 1.00 | 17.77 | B | C |
| ATOM | 4955 | CB | THR | B | 718 | 26.632 | 79.744 | 75.998 | 1.00 | 17.80 | B | C |
| ATOM | 4956 | OG1 | THR | B | 718 | 25.757 | 80.107 | 77.074 | 1.00 | 18.19 | B | O |
| ATOM | 4957 | CG2 | THR | B | 718 | 27.671 | 78.749 | 76.494 | 1.00 | 14.04 | B | C |
| ATOM | 4958 | C | THR | B | 718 | 26.188 | 81.944 | 75.019 | 1.00 | 17.89 | B | C |
| ATOM | 4959 | O | THR | B | 718 | 25.618 | 81.760 | 73.945 | 1.00 | 18.92 | B | O |
| ATOM | 4960 | N | ASN | B | 719 | 25.869 | 82.942 | 75.832 | 1.00 | 16.97 | B | N |
| ATOM | 4961 | CA | ASN | B | 719 | 24.779 | 83.875 | 75.521 | 1.00 | 15.47 | B | C |
| ATOM | 4962 | CB | ASN | B | 719 | 25.018 | 84.608 | 74.199 | 1.00 | 15.10 | B | C |
| ATOM | 4963 | CG | ASN | B | 719 | 24.339 | 85.982 | 74.158 | 1.00 | 15.92 | B | C |
| ATOM | 4964 | OD1 | ASN | B | 719 | 24.512 | 86.807 | 75.056 | 1.00 | 19.91 | B | O |
| ATOM | 4965 | ND2 | ASN | B | 719 | 23.565 | 86.226 | 73.112 | 1.00 | 15.55 | B | N |
| ATOM | 4966 | C | ASN | B | 719 | 23.436 | 83.150 | 75.466 | 1.00 | 14.53 | B | C |
| ATOM | 4967 | O | ASN | B | 719 | 22.521 | 83.559 | 74.752 | 1.00 | 13.32 | B | O |
| ATOM | 4968 | N | VAL | B | 720 | 23.329 | 82.066 | 76.228 | 1.00 | 14.12 | B | N |
| ATOM | 4969 | CA | VAL | B | 720 | 22.100 | 81.291 | 76.307 | 1.00 | 12.81 | B | C |
| ATOM | 4970 | CB | VAL | B | 720 | 22.384 | 79.774 | 76.236 | 1.00 | 14.83 | B | C |
| ATOM | 4971 | CG1 | VAL | B | 720 | 21.097 | 78.993 | 76.434 | 1.00 | 15.31 | B | C |
| ATOM | 4972 | CG2 | VAL | B | 720 | 23.005 | 79.422 | 74.896 | 1.00 | 13.32 | B | C |
| ATOM | 4973 | C | VAL | B | 720 | 21.473 | 81.618 | 77.657 | 1.00 | 13.81 | B | C |
| ATOM | 4974 | O | VAL | B | 720 | 22.104 | 81.449 | 78.696 | 1.00 | 17.06 | B | O |
| ATOM | 4975 | N | ALA | B | 721 | 20.233 | 82.093 | 77.639 | 1.00 | 13.72 | B | N |
| ATOM | 4976 | CA | ALA | B | 721 | 19.524 | 82.460 | 78.860 | 1.00 | 14.19 | B | C |
| ATOM | 4977 | CB | ALA | B | 721 | 18.117 | 82.935 | 78.511 | 1.00 | 12.61 | B | C |
| ATOM | 4978 | C | ALA | B | 721 | 19.449 | 81.310 | 79.849 | 1.00 | 11.96 | B | C |
| ATOM | 4979 | O | ALA | B | 721 | 19.294 | 80.161 | 79.459 | 1.00 | 13.11 | B | O |
| ATOM | 4980 | N | GLN | B | 722 | 19.555 | 81.617 | 81.136 | 1.00 | 12.78 | B | N |
| ATOM | 4981 | CA | GLN | B | 722 | 19.475 | 80.570 | 82.149 | 1.00 | 13.81 | B | C |
| ATOM | 4982 | CB | GLN | B | 722 | 20.021 | 81.076 | 83.484 | 1.00 | 14.66 | B | C |
| ATOM | 4983 | CG | GLN | B | 722 | 21.546 | 81.073 | 83.561 | 1.00 | 15.60 | B | C |
| ATOM | 4984 | CD | GLN | B | 722 | 22.145 | 79.676 | 83.444 | 1.00 | 19.93 | B | C |
| ATOM | 4985 | OE1 | GLN | B | 722 | 22.646 | 79.113 | 84.422 | 1.00 | 19.49 | B | O |
| ATOM | 4986 | NE2 | GLN | B | 722 | 22.100 | 79.114 | 82.244 | 1.00 | 19.13 | B | N |
| ATOM | 4987 | C | GLN | B | 722 | 18.016 | 80.135 | 82.282 | 1.00 | 13.95 | B | C |
| ATOM | 4988 | O | GLN | B | 722 | 17.716 | 79.036 | 82.765 | 1.00 | 14.65 | B | O |
| ATOM | 4989 | N | ILE | B | 723 | 17.109 | 80.999 | 81.841 | 1.00 | 11.57 | B | N |
| ATOM | 4990 | CA | ILE | B | 723 | 15.693 | 80.691 | 81.876 | 1.00 | 11.93 | B | C |
| ATOM | 4991 | CB | ILE | B | 723 | 14.850 | 81.897 | 81.433 | 1.00 | 11.15 | B | C |
| ATOM | 4992 | CG2 | ILE | B | 723 | 13.403 | 81.467 | 81.202 | 1.00 | 10.28 | B | C |
| ATOM | 4993 | CG1 | ILE | B | 723 | 14.922 | 82.991 | 82.497 | 1.00 | 12.70 | B | C |
| ATOM | 4994 | CD1 | ILE | B | 723 | 14.092 | 84.225 | 82.183 | 1.00 | 11.02 | B | C |
| ATOM | 4995 | C | ILE | B | 723 | 15.441 | 79.540 | 80.906 | 1.00 | 14.71 | B | C |
| ATOM | 4996 | O | ILE | B | 723 | 14.615 | 78.652 | 81.169 | 1.00 | 17.40 | B | O |
| ATOM | 4997 | N | ARG | B | 724 | 16.157 | 79.556 | 79.782 | 1.00 | 13.11 | B | N |
| ATOM | 4998 | CA | ARG | B | 724 | 16.009 | 78.513 | 78.769 | 1.00 | 11.55 | B | C |
| ATOM | 4999 | CB | ARG | B | 724 | 16.690 | 78.948 | 77.459 | 1.00 | 12.12 | B | C |
| ATOM | 5000 | CG | ARG | B | 724 | 16.616 | 77.939 | 76.304 | 1.00 | 6.50 | B | C |
| ATOM | 5001 | CD | ARG | B | 724 | 15.192 | 77.660 | 75.845 | 1.00 | 8.45 | B | C |
| ATOM | 5002 | NE | ARG | B | 724 | 14.530 | 78.844 | 75.296 | 1.00 | 13.77 | B | N |
| ATOM | 5003 | CZ | ARG | B | 724 | 14.567 | 79.213 | 74.014 | 1.00 | 12.95 | B | C |
| ATOM | 5004 | NH1 | ARG | B | 724 | 15.238 | 78.492 | 73.120 | 1.00 | 13.29 | B | N |
| ATOM | 5005 | NH2 | ARG | B | 724 | 13.937 | 80.311 | 73.625 | 1.00 | 8.90 | B | N |
| ATOM | 5006 | C | ARG | B | 724 | 16.610 | 77.214 | 79.285 | 1.00 | 9.02 | B | C |
| ATOM | 5007 | O | ARG | B | 724 | 16.017 | 76.145 | 79.134 | 1.00 | 8.99 | B | O |
| ATOM | 5008 | N | MET | B | 725 | 17.783 | 77.298 | 79.903 | 1.00 | 5.96 | B | N |
| ATOM | 5009 | CA | MET | B | 725 | 18.419 | 76.099 | 80.440 | 1.00 | 8.31 | B | C |
| ATOM | 5010 | CB | MET | B | 725 | 19.769 | 76.441 | 81.074 | 1.00 | 6.32 | B | C |
| ATOM | 5011 | CG | MET | B | 725 | 20.820 | 76.943 | 80.098 | 1.00 | 4.67 | B | C |
| ATOM | 5012 | SD | MET | B | 725 | 21.386 | 75.675 | 78.933 | 1.00 | 14.21 | B | S |
| ATOM | 5013 | CE | MET | B | 725 | 21.945 | 74.403 | 80.005 | 1.00 | 8.77 | B | C |
| ATOM | 5014 | C | MET | B | 725 | 17.519 | 75.432 | 81.483 | 1.00 | 10.20 | B | C |
| ATOM | 5015 | O | MET | B | 725 | 17.349 | 74.209 | 81.483 | 1.00 | 12.60 | B | O |
| ATOM | 5016 | N | ALA | B | 726 | 16.932 | 76.234 | 82.366 | 1.00 | 11.50 | B | N |
| ATOM | 5017 | CA | ALA | B | 726 | 16.060 | 75.695 | 83.405 | 1.00 | 11.38 | B | C |
| ATOM | 5018 | CB | ALA | B | 726 | 15.661 | 76.785 | 84.380 | 1.00 | 11.00 | B | C |
| ATOM | 5019 | C | ALA | B | 726 | 14.823 | 75.068 | 82.790 | 1.00 | 13.29 | B | C |
| ATOM | 5020 | O | ALA | B | 726 | 14.388 | 73.984 | 83.208 | 1.00 | 13.72 | B | O |
| ATOM | 5021 | N | TYR | B | 727 | 14.251 | 75.744 | 81.797 | 1.00 | 11.06 | B | N |
| ATOM | 5022 | CA | TYR | B | 727 | 13.065 | 75.216 | 81.143 | 1.00 | 8.87 | B | C |
| ATOM | 5023 | CB | TYR | B | 727 | 12.566 | 76.174 | 80.063 | 1.00 | 9.36 | B | C |
| ATOM | 5024 | CG | TYR | B | 727 | 11.482 | 75.557 | 79.215 | 1.00 | 9.48 | B | C |
| ATOM | 5025 | CD1 | TYR | B | 727 | 11.781 | 74.953 | 78.000 | 1.00 | 10.40 | B | C |
| ATOM | 5026 | CE1 | TYR | B | 727 | 10.785 | 74.348 | 77.232 | 1.00 | 9.26 | B | C |
| ATOM | 5027 | CD2 | TYR | B | 727 | 10.158 | 75.542 | 79.644 | 1.00 | 8.27 | B | C |
| ATOM | 5028 | CE2 | TYR | B | 727 | 9.156 | 74.938 | 78.881 | 1.00 | 8.61 | B | C |
| ATOM | 5029 | CZ | TYR | B | 727 | 9.478 | 74.346 | 77.680 | 1.00 | 8.81 | B | C |
| ATOM | 5030 | OH | TYR | B | 727 | 8.489 | 73.755 | 76.929 | 1.00 | 11.54 | B | O |
| ATOM | 5031 | C | TYR | B | 727 | 13.372 | 73.861 | 80.517 | 1.00 | 10.04 | B | C |
| ATOM | 5032 | O | TYR | B | 727 | 12.662 | 72.885 | 80.751 | 1.00 | 10.30 | B | O |
| ATOM | 5033 | N | ARG | B | 728 | 14.430 | 73.797 | 79.717 | 1.00 | 12.42 | B | N |
| ATOM | 5034 | CA | ARG | B | 728 | 14.808 | 72.538 | 79.069 | 1.00 | 13.66 | B | C |
| ATOM | 5035 | CB | ARG | B | 728 | 16.114 | 72.706 | 78.285 | 1.00 | 10.07 | B | C |
| ATOM | 5036 | CG | ARG | B | 728 | 16.023 | 73.648 | 77.100 | 1.00 | 10.03 | B | C |
| ATOM | 5037 | CD | ARG | B | 728 | 15.062 | 73.116 | 76.046 | 1.00 | 9.68 | B | C |
| ATOM | 5038 | NE | ARG | B | 728 | 15.082 | 73.940 | 74.844 | 1.00 | 11.39 | B | N |
| ATOM | 5039 | CZ | ARG | B | 728 | 14.164 | 73.882 | 73.886 | 1.00 | 8.65 | B | C |
| ATOM | 5040 | NH1 | ARG | B | 728 | 13.153 | 73.034 | 73.995 | 1.00 | 6.69 | B | N |
| ATOM | 5041 | NH2 | ARG | B | 728 | 14.263 | 74.672 | 72.824 | 1.00 | 7.94 | B | N |
| ATOM | 5042 | C | ARG | B | 728 | 15.008 | 71.442 | 80.105 | 1.00 | 14.11 | B | C |
| ATOM | 5043 | O | ARG | B | 728 | 14.481 | 70.333 | 79.982 | 1.00 | 15.35 | B | O |
| ATOM | 5044 | N | TYR | B | 729 | 15.772 | 71.763 | 81.139 | 1.00 | 13.47 | B | N |
| ATOM | 5045 | CA | TYR | B | 729 | 16.067 | 70.795 | 82.176 | 1.00 | 12.95 | B | C |
| ATOM | 5046 | CB | TYR | B | 729 | 17.005 | 71.420 | 83.197 | 1.00 | 14.48 | B | C |
| ATOM | 5047 | CG | TYR | B | 729 | 17.625 | 70.416 | 84.138 | 1.00 | 19.47 | B | C |
| ATOM | 5048 | CD1 | TYR | B | 729 | 18.246 | 69.261 | 83.656 | 1.00 | 19.25 | B | C |
| ATOM | 5049 | CE1 | TYR | B | 729 | 18.818 | 68.340 | 84.531 | 1.00 | 20.95 | B | C |
| ATOM | 5050 | CD2 | TYR | B | 729 | 17.591 | 70.623 | 85.521 | 1.00 | 20.52 | B | C |
| ATOM | 5051 | CE2 | TYR | B | 729 | 18.157 | 69.716 | 86.399 | 1.00 | 21.01 | B | C |
| ATOM | 5052 | CZ | TYR | B | 729 | 18.768 | 68.579 | 85.905 | 1.00 | 24.67 | B | C |
| ATOM | 5053 | OH | TYR | B | 729 | 19.332 | 67.688 | 86.802 | 1.00 | 29.63 | B | O |
| ATOM | 5054 | C | TYR | B | 729 | 14.834 | 70.252 | 82.870 | 1.00 | 13.03 | B | C |
| ATOM | 5055 | O | TYR | B | 729 | 14.651 | 69.040 | 82.968 | 1.00 | 13.85 | B | O |
| ATOM | 5056 | N | GLU | B | 730 | 13.981 | 71.149 | 83.352 | 1.00 | 12.92 | B | N |
| ATOM | 5057 | CA | GLU | B | 730 | 12.778 | 70.731 | 84.057 | 1.00 | 12.27 | B | C |
| ATOM | 5058 | CB | GLU | B | 730 | 12.034 | 71.949 | 84.607 | 1.00 | 12.18 | B | C |
| ATOM | 5059 | CG | GLU | B | 730 | 12.891 | 72.850 | 85.467 | 1.00 | 12.25 | B | C |
| ATOM | 5060 | CD | GLU | B | 730 | 12.204 | 74.152 | 85.789 | 1.00 | 16.97 | B | C |
| ATOM | 5061 | OE1 | GLU | B | 730 | 12.865 | 75.061 | 86.335 | 1.00 | 21.39 | B | O |
| ATOM | 5062 | OE2 | GLU | B | 730 | 10.997 | 74.273 | 85.497 | 1.00 | 20.15 | B | O |
| ATOM | 5063 | C | GLU | B | 730 | 11.830 | 69.898 | 83.211 | 1.00 | 12.09 | B | C |
| ATOM | 5064 | O | GLU | B | 730 | 11.298 | 68.892 | 83.690 | 1.00 | 12.21 | B | O |
| ATOM | 5065 | N | THR | B | 731 | 11.609 | 70.294 | 81.958 | 1.00 | 12.33 | B | N |
| ATOM | 5066 | CA | THR | B | 731 | 10.691 | 69.520 | 81.140 | 1.00 | 11.36 | B | C |
| ATOM | 5067 | CB | THR | B | 731 | 10.166 | 70.337 | 79.924 | 1.00 | 14.29 | B | C |
| ATOM | 5068 | OG1 | THR | B | 731 | 10.667 | 69.789 | 78.707 | 1.00 | 16.88 | B | O |
| ATOM | 5069 | CG2 | THR | B | 731 | 10.557 | 71.787 | 80.043 | 1.00 | 6.49 | B | C |
| ATOM | 5070 | C | THR | B | 731 | 11.294 | 68.179 | 80.722 | 1.00 | 11.28 | B | C |
| ATOM | 5071 | O | THR | B | 731 | 10.565 | 67.221 | 80.471 | 1.00 | 10.75 | B | O |
| ATOM | 5072 | N | TRP | B | 732 | 12.622 | 68.088 | 80.690 | 1.00 | 11.99 | B | N |
| ATOM | 5073 | CA | TRP | B | 732 | 13.275 | 66.822 | 80.343 | 1.00 | 10.29 | B | C |
| ATOM | 5074 | CB | TRP | B | 732 | 14.756 | 67.046 | 80.031 | 1.00 | 9.68 | B | C |
| ATOM | 5075 | CG | TRP | B | 732 | 15.527 | 65.794 | 79.689 | 1.00 | 10.32 | B | C |
| ATOM | 5076 | CD2 | TRP | B | 732 | 16.948 | 65.604 | 79.797 | 1.00 | 8.70 | B | C |
| ATOM | 5077 | CE2 | TRP | B | 732 | 17.234 | 64.292 | 79.351 | 1.00 | 7.12 | B | C |
| ATOM | 5078 | CE3 | TRP | B | 732 | 18.008 | 66.419 | 80.229 | 1.00 | 9.29 | B | C |
| ATOM | 5079 | CD1 | TRP | B | 732 | 15.024 | 64.616 | 79.196 | 1.00 | 12.01 | B | C |
| ATOM | 5080 | NE1 | TRP | B | 732 | 16.048 | 63.708 | 78.988 | 1.00 | 5.59 | B | N |
| ATOM | 5081 | CZ2 | TRP | B | 732 | 18.534 | 63.775 | 79.322 | 1.00 | 7.17 | B | C |
| ATOM | 5082 | CZ3 | TRP | B | 732 | 19.311 | 65.900 | 80.198 | 1.00 | 7.55 | B | C |
| ATOM | 5083 | CH2 | TRP | B | 732 | 19.556 | 64.589 | 79.747 | 1.00 | 7.12 | B | C |
| ATOM | 5084 | C | TRP | B | 732 | 13.135 | 65.872 | 81.533 | 1.00 | 13.31 | B | C |
| ATOM | 5085 | O | TRP | B | 732 | 12.801 | 64.692 | 81.370 | 1.00 | 13.80 | B | O |
| ATOM | 5086 | N | CYS | B | 733 | 13.384 | 66.389 | 82.735 | 1.00 | 15.44 | B | N |
| ATOM | 5087 | CA | CYS | B | 733 | 13.265 | 65.576 | 83.956 | 1.00 | 16.50 | B | C |
| ATOM | 5088 | CB | CYS | B | 733 | 13.712 | 66.382 | 85.179 | 1.00 | 12.89 | B | C |
| ATOM | 5089 | SG | CYS | B | 733 | 15.500 | 66.506 | 85.361 | 1.00 | 16.07 | B | S |
| ATOM | 5090 | C | CYS | B | 733 | 11.822 | 65.108 | 84.159 | 1.00 | 13.08 | B | C |
| ATOM | 5091 | O | CYS | B | 733 | 11.571 | 63.960 | 84.533 | 1.00 | 14.32 | B | O |
| ATOM | 5092 | N | TYR | B | 734 | 10.877 | 66.001 | 83.902 | 1.00 | 11.71 | B | N |
| ATOM | 5093 | CA | TYR | B | 734 | 9.472 | 65.678 | 84.060 | 1.00 | 12.82 | B | C |
| ATOM | 5094 | CB | TYR | B | 734 | 8.623 | 66.894 | 83.689 | 1.00 | 14.29 | B | C |
| ATOM | 5095 | CG | TYR | B | 734 | 7.160 | 66.772 | 84.045 | 1.00 | 15.46 | B | C |
| ATOM | 5096 | CD1 | TYR | B | 734 | 6.664 | 67.277 | 85.246 | 1.00 | 18.31 | B | C |
| ATOM | 5097 | CE1 | TYR | B | 734 | 5.309 | 67.186 | 85.568 | 1.00 | 17.37 | B | C |
| ATOM | 5098 | CD2 | TYR | B | 734 | 6.267 | 66.169 | 83.175 | 1.00 | 21.15 | B | C |
| ATOM | 5099 | CE2 | TYR | B | 734 | 4.910 | 66.072 | 83.485 | 1.00 | 24.38 | B | C |
| ATOM | 5100 | CZ | TYR | B | 734 | 4.439 | 66.583 | 84.681 | 1.00 | 23.04 | B | C |
| ATOM | 5101 | OH | TYR | B | 734 | 3.093 | 66.503 | 84.969 | 1.00 | 27.16 | B | O |
| ATOM | 5102 | C | TYR | B | 734 | 9.058 | 64.477 | 83.218 | 1.00 | 15.24 | B | C |
| ATOM | 5103 | O | TYR | B | 734 | 8.313 | 63.618 | 83.682 | 1.00 | 20.19 | B | O |
| ATOM | 5104 | N | GLU | B | 735 | 9.543 | 64.403 | 81.981 | 1.00 | 16.37 | B | N |
| ATOM | 5105 | CA | GLU | B | 735 | 9.178 | 63.300 | 81.099 | 1.00 | 14.47 | B | C |
| ATOM | 5106 | CB | GLU | B | 735 | 9.670 | 63.570 | 79.671 | 1.00 | 16.47 | B | C |
| ATOM | 5107 | CG | GLU | B | 735 | 8.960 | 64.722 | 78.955 | 1.00 | 14.89 | B | C |
| ATOM | 5108 | CD | GLU | B | 735 | 7.451 | 64.537 | 78.869 | 1.00 | 13.08 | B | C |
| ATOM | 5109 | OE1 | GLU | B | 735 | 6.993 | 63.455 | 78.448 | 1.00 | 10.71 | B | O |
| ATOM | 5110 | OE2 | GLU | B | 735 | 6.721 | 65.489 | 79.221 | 1.00 | 17.15 | B | O |
| ATOM | 5111 | C | GLU | B | 735 | 9.740 | 61.974 | 81.592 | 1.00 | 12.99 | B | C |
| ATOM | 5112 | O | GLU | B | 735 | 9.047 | 60.955 | 81.606 | 1.00 | 10.55 | B | O |
| ATOM | 5113 | N | LEU | B | 736 | 11.005 | 61.985 | 81.990 | 1.00 | 14.10 | B | N |
| ATOM | 5114 | CA | LEU | B | 736 | 11.647 | 60.771 | 82.490 | 1.00 | 15.98 | B | C |
| ATOM | 5115 | CB | LEU | B | 736 | 13.112 | 61.046 | 82.818 | 1.00 | 12.43 | B | C |
| ATOM | 5116 | CG | LEU | B | 736 | 14.015 | 61.256 | 81.606 | 1.00 | 14.27 | B | C |
| ATOM | 5117 | CD1 | LEU | B | 736 | 15.277 | 62.013 | 82.016 | 1.00 | 13.21 | B | C |
| ATOM | 5118 | CD2 | LEU | B | 736 | 14.351 | 59.906 | 80.997 | 1.00 | 11.10 | B | C |
| ATOM | 5119 | C | LEU | B | 736 | 10.933 | 60.269 | 83.739 | 1.00 | 16.11 | B | C |
| ATOM | 5120 | O | LEU | B | 736 | 10.707 | 59.071 | 83.910 | 1.00 | 16.18 | B | O |
| ATOM | 5121 | N | ASN | B | 737 | 10.573 | 61.202 | 84.608 | 1.00 | 16.97 | B | N |
| ATOM | 5122 | CA | ASN | B | 737 | 9.886 | 60.869 | 85.840 | 1.00 | 17.62 | B | C |
| ATOM | 5123 | CB | ASN | B | 737 | 9.692 | 62.134 | 86.672 | 1.00 | 22.09 | B | C |
| ATOM | 5124 | CG | ASN | B | 737 | 9.219 | 61.834 | 88.063 | 1.00 | 23.84 | B | C |
| ATOM | 5125 | OD1 | ASN | B | 737 | 9.847 | 61.064 | 88.782 | 1.00 | 26.42 | B | O |
| ATOM | 5126 | ND2 | ASN | B | 737 | 8.100 | 62.434 | 88.455 | 1.00 | 26.93 | B | N |
| ATOM | 5127 | C | ASN | B | 737 | 8.542 | 60.187 | 85.617 | 1.00 | 17.46 | B | C |
| ATOM | 5128 | O | ASN | B | 737 | 8.152 | 59.309 | 86.385 | 1.00 | 18.76 | B | O |
| ATOM | 5129 | N | LEU | B | 738 | 7.830 | 60.586 | 84.568 | 1.00 | 19.52 | B | N |
| ATOM | 5130 | CA | LEU | B | 738 | 6.528 | 59.989 | 84.278 | 1.00 | 19.30 | B | C |
| ATOM | 5131 | CB | LEU | B | 738 | 5.935 | 60.580 | 82.997 | 1.00 | 15.95 | B | C |
| ATOM | 5132 | CG | LEU | B | 738 | 5.409 | 62.010 | 83.105 | 1.00 | 16.49 | B | C |
| ATOM | 5133 | CD1 | LEU | B | 738 | 5.028 | 62.520 | 81.723 | 1.00 | 14.89 | B | C |
| ATOM | 5134 | CD2 | LEU | B | 738 | 4.212 | 62.040 | 84.035 | 1.00 | 13.09 | B | C |
| ATOM | 5135 | C | LEU | B | 738 | 6.671 | 58.484 | 84.123 | 1.00 | 18.81 | B | C |
| ATOM | 5136 | O | LEU | B | 738 | 5.782 | 57.718 | 84.491 | 1.00 | 19.98 | B | O |
| ATOM | 5137 | N | ILE | B | 739 | 7.803 | 58.068 | 83.576 | 1.00 | 19.35 | B | N |
| ATOM | 5138 | CA | ILE | B | 739 | 8.070 | 56.657 | 83.366 | 1.00 | 19.46 | B | C |
| ATOM | 5139 | CB | ILE | B | 739 | 9.239 | 56.458 | 82.387 | 1.00 | 18.57 | B | C |
| ATOM | 5140 | CG2 | ILE | B | 739 | 9.568 | 54.973 | 82.261 | 1.00 | 12.73 | B | C |
| ATOM | 5141 | CG1 | ILE | B | 739 | 8.861 | 57.039 | 81.019 | 1.00 | 20.39 | B | C |
| ATOM | 5142 | CD1 | ILE | B | 739 | 10.044 | 57.347 | 80.123 | 1.00 | 22.95 | B | C |
| ATOM | 5143 | C | ILE | B | 739 | 8.394 | 55.964 | 84.680 | 1.00 | 21.40 | B | C |
| ATOM | 5144 | O | ILE | B | 739 | 7.896 | 54.869 | 84.946 | 1.00 | 20.40 | B | O |
| ATOM | 5145 | N | ALA | B | 740 | 9.227 | 56.602 | 85.500 | 1.00 | 19.60 | B | N |
| ATOM | 5146 | CA | ALA | B | 740 | 9.606 | 56.039 | 86.792 | 1.00 | 18.93 | B | C |
| ATOM | 5147 | CB | ALA | B | 740 | 10.570 | 56.974 | 87.504 | 1.00 | 16.82 | B | C |
| ATOM | 5148 | C | ALA | B | 740 | 8.363 | 55.809 | 87.651 | 1.00 | 20.57 | B | C |
| ATOM | 5149 | O | ALA | B | 740 | 8.228 | 54.773 | 88.296 | 1.00 | 19.09 | B | O |
| ATOM | 5150 | N | GLU | B | 741 | 7.454 | 56.779 | 87.645 | 1.00 | 21.07 | B | N |
| ATOM | 5151 | CA | GLU | B | 741 | 6.221 | 56.681 | 88.412 | 1.00 | 21.19 | B | C |
| ATOM | 5152 | CB | GLU | B | 741 | 5.444 | 57.993 | 88.322 | 1.00 | 24.66 | B | C |
| ATOM | 5153 | CG | GLU | B | 741 | 6.212 | 59.204 | 88.819 | 1.00 | 27.93 | B | C |
| ATOM | 5154 | CD | GLU | B | 741 | 6.232 | 59.301 | 90.330 | 1.00 | 29.79 | B | C |
| ATOM | 5155 | OE1 | GLU | B | 741 | 7.336 | 59.306 | 90.912 | 1.00 | 31.54 | B | O |
| ATOM | 5156 | OE2 | GLU | B | 741 | 5.143 | 59.374 | 90.936 | 1.00 | 33.00 | B | O |
| ATOM | 5157 | C | GLU | B | 741 | 5.329 | 55.538 | 87.937 | 1.00 | 22.02 | B | C |
| ATOM | 5158 | O | GLU | B | 741 | 4.686 | 54.870 | 88.747 | 1.00 | 23.72 | B | O |
| ATOM | 5159 | N | GLY | B | 742 | 5.284 | 55.317 | 86.626 | 1.00 | 20.74 | B | N |
| ATOM | 5160 | CA | GLY | B | 742 | 4.456 | 54.251 | 86.093 | 1.00 | 20.67 | B | C |
| ATOM | 5161 | C | GLY | B | 742 | 4.952 | 52.883 | 86.506 | 1.00 | 24.49 | B | C |
| ATOM | 5162 | O | GLY | B | 742 | 4.239 | 51.890 | 86.384 | 1.00 | 27.37 | B | O |
| ATOM | 5163 | N | LEU | B | 743 | 6.183 | 52.834 | 87.001 | 1.00 | 27.85 | B | N |
| ATOM | 5164 | CA | LEU | B | 743 | 6.811 | 51.590 | 87.434 | 1.00 | 30.10 | B | C |
| ATOM | 5165 | CB | LEU | B | 743 | 8.217 | 51.483 | 86.834 | 1.00 | 28.45 | B | C |
| ATOM | 5166 | CG | LEU | B | 743 | 8.481 | 50.752 | 85.507 | 1.00 | 27.17 | B | C |
| ATOM | 5167 | CD1 | LEU | B | 743 | 7.198 | 50.498 | 84.743 | 1.00 | 25.35 | B | C |
| ATOM | 5168 | CD2 | LEU | B | 743 | 9.440 | 51.592 | 84.684 | 1.00 | 24.52 | B | C |
| ATOM | 5169 | C | LEU | B | 743 | 6.918 | 51.516 | 88.959 | 1.00 | 33.57 | B | C |
| ATOM | 5170 | O | LEU | B | 743 | 7.244 | 50.469 | 89.514 | 1.00 | 34.38 | B | O |
| ATOM | 5171 | N | LYS | B | 744 | 6.645 | 52.633 | 89.627 | 1.00 | 36.47 | B | N |
| ATOM | 5172 | CA | LYS | B | 744 | 6.724 | 52.719 | 91.086 | 1.00 | 39.04 | B | C |
| ATOM | 5173 | CB | LYS | B | 744 | 6.317 | 54.122 | 91.550 | 1.00 | 33.95 | B | C |
| ATOM | 5174 | CG | LYS | B | 744 | 7.436 | 54.922 | 92.184 | 1.00 | 30.97 | B | C |
| ATOM | 5175 | CD | LYS | B | 744 | 6.990 | 55.525 | 93.500 | 1.00 | 33.43 | B | C |
| ATOM | 5176 | CE | LYS | B | 744 | 7.221 | 57.027 | 93.530 | 1.00 | 36.86 | B | C |
| ATOM | 5177 | NZ | LYS | B | 744 | 6.488 | 57.679 | 94.661 | 1.00 | 37.96 | B | N |
| ATOM | 5178 | C | LYS | B | 744 | 5.871 | 51.686 | 91.823 | 1.00 | 44.39 | B | C |
| ATOM | 5179 | O | LYS | B | 744 | 4.854 | 51.212 | 91.305 | 1.00 | 44.72 | B | O |
| ATOM | 5180 | N | SER | B | 745 | 6.298 | 51.354 | 93.042 | 1.00 | 49.49 | B | N |
| ATOM | 5181 | CA | SER | B | 745 | 5.600 | 50.398 | 93.898 | 1.00 | 53.13 | B | C |
| ATOM | 5182 | CB | SER | B | 745 | 5.423 | 49.062 | 93.174 | 1.00 | 53.77 | B | C |
| ATOM | 5183 | OG | SER | B | 745 | 4.069 | 48.648 | 93.223 | 1.00 | 56.23 | B | O |
| ATOM | 5184 | C | SER | B | 745 | 6.358 | 50.180 | 95.211 | 1.00 | 56.69 | B | C |
| ATOM | 5185 | O | SER | B | 745 | 6.983 | 49.103 | 95.369 | 1.00 | 58.68 | B | O |
| ATOM | 5186 | OT | SER | B | 745 | 6.318 | 51.093 | 96.070 | 1.00 | 59.71 | B | O |
| ATOM | 5187 | CB | SER | D | 106 | −10.786 | 60.660 | 13.610 | 1.00 | 39.90 | D | C |
| ATOM | 5188 | OG | SER | D | 106 | −11.853 | 60.326 | 14.483 | 1.00 | 42.15 | D | O |
| ATOM | 5189 | C | SER | D | 106 | −12.831 | 60.945 | 12.191 | 1.00 | 39.78 | D | C |
| ATOM | 5190 | O | SER | D | 106 | −13.570 | 61.854 | 12.582 | 1.00 | 41.94 | D | O |
| ATOM | 5191 | N | SER | D | 106 | −10.900 | 62.503 | 11.944 | 1.00 | 36.59 | D | N |
| ATOM | 5192 | CA | SER | D | 106 | −11.308 | 61.094 | 12.234 | 1.00 | 39.23 | D | C |
| ATOM | 5193 | N | PRO | D | 107 | −13.322 | 59.787 | 11.725 | 1.00 | 37.89 | D | N |
| ATOM | 5194 | CD | PRO | D | 107 | −12.542 | 58.629 | 11.260 | 1.00 | 36.48 | D | C |
| ATOM | 5195 | CA | PRO | D | 107 | −14.767 | 59.545 | 11.636 | 1.00 | 38.32 | D | C |
| ATOM | 5196 | CB | PRO | D | 107 | −14.871 | 58.205 | 10.898 | 1.00 | 34.81 | D | C |
| ATOM | 5197 | CG | PRO | D | 107 | −13.504 | 57.909 | 10.377 | 1.00 | 33.29 | D | C |
| ATOM | 5198 | C | PRO | D | 107 | −15.520 | 59.514 | 12.970 | 1.00 | 39.37 | D | C |
| ATOM | 5199 | O | PRO | D | 107 | −16.724 | 59.771 | 13.007 | 1.00 | 40.53 | D | O |
| ATOM | 5200 | N | THR | D | 108 | −14.818 | 59.217 | 14.061 | 1.00 | 40.71 | D | N |
| ATOM | 5201 | CA | THR | D | 108 | −15.462 | 59.120 | 15.374 | 1.00 | 40.53 | D | C |
| ATOM | 5202 | CB | THR | D | 108 | −14.697 | 58.135 | 16.297 | 1.00 | 41.63 | D | C |
| ATOM | 5203 | OG1 | THR | D | 108 | −13.605 | 58.816 | 16.933 | 1.00 | 39.77 | D | O |
| ATOM | 5204 | CG2 | THR | D | 108 | −14.162 | 56.946 | 15.484 | 1.00 | 40.89 | D | C |
| ATOM | 5205 | C | THR | D | 108 | −15.672 | 60.428 | 16.142 | 1.00 | 38.99 | D | C |
| ATOM | 5206 | O | THR | D | 108 | −16.097 | 60.402 | 17.298 | 1.00 | 38.98 | D | O |
| ATOM | 5207 | N | TYR | D | 109 | −15.389 | 61.565 | 15.512 | 1.00 | 37.51 | D | N |
| ATOM | 5208 | CA | TYR | D | 109 | −15.567 | 62.852 | 16.184 | 1.00 | 34.38 | D | C |
| ATOM | 5209 | CB | TYR | D | 109 | −14.354 | 63.752 | 15.933 | 1.00 | 31.56 | D | C |
| ATOM | 5210 | CG | TYR | D | 109 | −13.247 | 63.541 | 16.940 | 1.00 | 33.80 | D | C |
| ATOM | 5211 | CD1 | TYR | D | 109 | −12.943 | 62.261 | 17.414 | 1.00 | 35.23 | D | C |
| ATOM | 5212 | CE1 | TYR | D | 109 | −11.932 | 62.059 | 18.352 | 1.00 | 32.17 | D | C |
| ATOM | 5213 | CD2 | TYR | D | 109 | −12.510 | 64.614 | 17.431 | 1.00 | 32.16 | D | C |
| ATOM | 5214 | CE2 | TYR | D | 109 | −11.499 | 64.422 | 18.368 | 1.00 | 32.23 | D | C |
| ATOM | 5215 | CZ | TYR | D | 109 | −11.215 | 63.144 | 18.824 | 1.00 | 32.24 | D | C |
| ATOM | 5216 | OH | TYR | D | 109 | −10.208 | 62.954 | 19.746 | 1.00 | 32.98 | D | O |
| ATOM | 5217 | C | TYR | D | 109 | −16.842 | 63.562 | 15.741 | 1.00 | 31.88 | D | C |
| ATOM | 5218 | O | TYR | D | 109 | −17.046 | 64.741 | 16.031 | 1.00 | 31.02 | D | O |
| ATOM | 5219 | N | GLN | D | 110 | −17.702 | 62.831 | 15.047 | 1.00 | 30.44 | D | N |
| ATOM | 5220 | CA | GLN | D | 110 | −18.961 | 63.382 | 14.557 | 1.00 | 32.43 | D | C |
| ATOM | 5221 | CB | GLN | D | 110 | −19.754 | 62.299 | 13.812 | 1.00 | 33.58 | D | C |
| ATOM | 5222 | CG | GLN | D | 110 | −20.939 | 62.826 | 13.010 | 1.00 | 33.76 | D | C |
| ATOM | 5223 | CD | GLN | D | 110 | −20.507 | 63.716 | 11.859 | 1.00 | 33.74 | D | C |
| ATOM | 5224 | OE1 | GLN | D | 110 | −19.326 | 63.757 | 11.503 | 1.00 | 34.77 | D | O |
| ATOM | 5225 | NE2 | GLN | D | 110 | −21.461 | 64.437 | 11.271 | 1.00 | 31.58 | D | N |
| ATOM | 5226 | C | GLN | D | 110 | −19.808 | 63.907 | 15.703 | 1.00 | 29.90 | D | C |
| ATOM | 5227 | O | GLN | D | 110 | −20.683 | 64.755 | 15.517 | 1.00 | 31.13 | D | O |
| ATOM | 5228 | N | THR | D | 111 | −19.525 | 63.402 | 16.893 | 1.00 | 29.18 | D | N |
| ATOM | 5229 | CA | THR | D | 111 | −20.287 | 63.758 | 18.073 | 1.00 | 26.63 | D | C |
| ATOM | 5230 | CB | THR | D | 111 | −20.717 | 62.460 | 18.776 | 1.00 | 26.52 | D | C |
| ATOM | 5231 | OG1 | THR | D | 111 | −21.960 | 62.668 | 19.443 | 1.00 | 30.08 | D | O |
| ATOM | 5232 | CG2 | THR | D | 111 | −19.657 | 62.007 | 19.770 | 1.00 | 27.11 | D | C |
| ATOM | 5233 | C | THR | D | 111 | −19.556 | 64.685 | 19.053 | 1.00 | 24.89 | D | C |
| ATOM | 5234 | O | THR | D | 111 | −20.137 | 65.137 | 20.040 | 1.00 | 23.41 | D | O |
| ATOM | 5235 | N | VAL | D | 112 | −18.288 | 64.971 | 18.759 | 1.00 | 22.88 | D | N |
| ATOM | 5236 | CA | VAL | D | 112 | −17.440 | 65.825 | 19.596 | 1.00 | 19.75 | D | C |
| ATOM | 5237 | CB | VAL | D | 112 | −15.965 | 65.348 | 19.555 | 1.00 | 15.91 | D | C |
| ATOM | 5238 | CG1 | VAL | D | 112 | −15.125 | 66.188 | 20.496 | 1.00 | 13.00 | D | C |
| ATOM | 5239 | CG2 | VAL | D | 112 | −15.873 | 63.873 | 19.916 | 1.00 | 11.16 | D | C |
| ATOM | 5240 | C | VAL | D | 112 | −17.445 | 67.301 | 19.186 | 1.00 | 19.15 | D | C |
| ATOM | 5241 | O | VAL | D | 112 | −17.084 | 67.635 | 18.064 | 1.00 | 22.26 | D | O |
| ATOM | 5242 | N | PRO | D | 113 | −17.845 | 68.202 | 20.094 | 1.00 | 18.31 | D | N |
| ATOM | 5243 | CD | PRO | D | 113 | −18.336 | 67.955 | 21.456 | 1.00 | 16.66 | D | C |
| ATOM | 5244 | CA | PRO | D | 113 | −17.869 | 69.632 | 19.773 | 1.00 | 17.80 | D | C |
| ATOM | 5245 | CB | PRO | D | 113 | −18.649 | 70.258 | 20.933 | 1.00 | 14.66 | D | C |
| ATOM | 5246 | CG | PRO | D | 113 | −19.267 | 69.106 | 21.669 | 1.00 | 14.17 | D | C |
| ATOM | 5247 | C | PRO | D | 113 | −16.468 | 70.214 | 19.674 | 1.00 | 18.68 | D | C |
| ATOM | 5248 | O | PRO | D | 113 | −15.489 | 69.584 | 20.065 | 1.00 | 19.76 | D | O |
| ATOM | 5249 | N | ASP | D | 114 | −16.378 | 71.423 | 19.140 | 1.00 | 22.35 | D | N |
| ATOM | 5250 | CA | ASP | D | 114 | −15.100 | 72.095 | 19.010 | 1.00 | 23.20 | D | C |
| ATOM | 5251 | CB | ASP | D | 114 | −15.222 | 73.309 | 18.086 | 1.00 | 27.14 | D | C |
| ATOM | 5252 | CG | ASP | D | 114 | −15.362 | 72.930 | 16.624 | 1.00 | 32.81 | D | C |
| ATOM | 5253 | OD1 | ASP | D | 114 | −14.884 | 71.843 | 16.231 | 1.00 | 36.57 | D | O |
| ATOM | 5254 | OD2 | ASP | D | 114 | −15.951 | 73.729 | 15.863 | 1.00 | 33.41 | D | O |
| ATOM | 5255 | C | ASP | D | 114 | −14.694 | 72.584 | 20.390 | 1.00 | 22.25 | D | C |
| ATOM | 5256 | O | ASP | D | 114 | −15.547 | 72.866 | 21.224 | 1.00 | 24.03 | D | O |
| ATOM | 5257 | N | PHE | D | 115 | −13.391 | 72.671 | 20.627 | 1.00 | 19.55 | D | N |
| ATOM | 5258 | CA | PHE | D | 115 | −12.865 | 73.182 | 21.884 | 1.00 | 17.22 | D | C |
| ATOM | 5259 | CB | PHE | D | 115 | −13.080 | 72.180 | 23.032 | 1.00 | 15.91 | D | C |
| ATOM | 5260 | CG | PHE | D | 115 | −12.270 | 70.919 | 22.926 | 1.00 | 12.17 | D | C |
| ATOM | 5261 | CD1 | PHE | D | 115 | −12.735 | 69.840 | 22.184 | 1.00 | 11.82 | D | C |
| ATOM | 5262 | CD2 | PHE | D | 115 | −11.066 | 70.790 | 23.610 | 1.00 | 7.69 | D | C |
| ATOM | 5263 | CE1 | PHE | D | 115 | −12.010 | 68.653 | 22.130 | 1.00 | 9.31 | D | C |
| ATOM | 5264 | CE2 | PHE | D | 115 | −10.339 | 69.606 | 23.557 | 1.00 | 6.14 | D | C |
| ATOM | 5265 | CZ | PHE | D | 115 | −10.812 | 68.540 | 22.819 | 1.00 | 6.21 | D | C |
| ATOM | 5266 | C | PHE | D | 115 | −11.391 | 73.497 | 21.663 | 1.00 | 17.03 | D | C |
| ATOM | 5267 | O | PHE | D | 115 | −10.766 | 72.945 | 20.759 | 1.00 | 18.77 | D | O |
| ATOM | 5268 | N | GLN | D | 116 | −10.842 | 74.403 | 22.462 | 1.00 | 15.50 | D | N |
| ATOM | 5269 | CA | GLN | D | 116 | −9.451 | 74.796 | 22.305 | 1.00 | 14.41 | D | C |
| ATOM | 5270 | CB | GLN | D | 116 | −9.228 | 76.153 | 22.962 | 1.00 | 16.39 | D | C |
| ATOM | 5271 | CG | GLN | D | 116 | −10.049 | 77.263 | 22.325 | 1.00 | 16.16 | D | C |
| ATOM | 5272 | CD | GLN | D | 116 | −9.816 | 78.615 | 22.969 | 1.00 | 21.84 | D | C |
| ATOM | 5273 | OE1 | GLN | D | 116 | −10.418 | 78.937 | 23.995 | 1.00 | 21.89 | D | O |
| ATOM | 5274 | NE2 | GLN | D | 116 | −8.940 | 79.422 | 22.363 | 1.00 | 18.50 | D | N |
| ATOM | 5275 | C | GLN | D | 116 | −8.476 | 73.773 | 22.853 | 1.00 | 16.48 | D | C |
| ATOM | 5276 | O | GLN | D | 116 | −8.659 | 73.237 | 23.946 | 1.00 | 20.95 | D | O |
| ATOM | 5277 | N | ARG | D | 117 | −7.432 | 73.504 | 22.081 | 1.00 | 16.57 | D | N |
| ATOM | 5278 | CA | ARG | D | 117 | −6.422 | 72.537 | 22.474 | 1.00 | 15.61 | D | C |
| ATOM | 5279 | CB | ARG | D | 117 | −6.280 | 71.467 | 21.394 | 1.00 | 15.66 | D | C |
| ATOM | 5280 | CG | ARG | D | 117 | −7.394 | 70.430 | 21.407 | 1.00 | 18.68 | D | C |
| ATOM | 5281 | CD | ARG | D | 117 | −7.458 | 69.697 | 20.094 | 1.00 | 19.57 | D | C |
| ATOM | 5282 | NE | ARG | D | 117 | −8.487 | 68.662 | 20.072 | 1.00 | 19.67 | D | N |
| ATOM | 5283 | CZ | ARG | D | 117 | −9.714 | 68.842 | 19.597 | 1.00 | 18.19 | D | C |
| ATOM | 5284 | NH1 | ARG | D | 117 | −10.067 | 70.018 | 19.111 | 1.00 | 19.26 | D | N |
| ATOM | 5285 | NH2 | ARG | D | 117 | −10.578 | 67.838 | 19.576 | 1.00 | 20.08 | D | N |
| ATOM | 5286 | C | ARG | D | 117 | −5.070 | 73.181 | 22.713 | 1.00 | 15.31 | D | C |
| ATOM | 5287 | O | ARG | D | 117 | −4.816 | 74.305 | 22.281 | 1.00 | 12.20 | D | O |
| ATOM | 5288 | N | VAL | D | 118 | −4.203 | 72.459 | 23.412 | 1.00 | 14.88 | D | N |
| ATOM | 5289 | CA | VAL | D | 118 | −2.868 | 72.953 | 23.682 | 1.00 | 18.11 | D | C |
| ATOM | 5290 | CB | VAL | D | 118 | −2.567 | 73.037 | 25.217 | 1.00 | 18.73 | D | C |
| ATOM | 5291 | CG1 | VAL | D | 118 | −3.696 | 72.420 | 26.009 | 1.00 | 16.26 | D | C |
| ATOM | 5292 | CG2 | VAL | D | 118 | −1.233 | 72.377 | 25.542 | 1.00 | 12.15 | D | C |
| ATOM | 5293 | C | VAL | D | 118 | −1.891 | 72.018 | 23.001 | 1.00 | 19.66 | D | C |
| ATOM | 5294 | O | VAL | D | 118 | −1.879 | 70.814 | 23.253 | 1.00 | 18.62 | D | O |
| ATOM | 5295 | N | GLN | D | 119 | −1.082 | 72.577 | 22.113 | 1.00 | 23.01 | D | N |
| ATOM | 5296 | CA | GLN | D | 119 | −0.111 | 71.772 | 21.402 | 1.00 | 25.97 | D | C |
| ATOM | 5297 | CB | GLN | D | 119 | −0.507 | 71.625 | 19.931 | 1.00 | 31.29 | D | C |
| ATOM | 5298 | CG | GLN | D | 119 | −0.930 | 72.913 | 19.252 | 1.00 | 39.62 | D | C |
| ATOM | 5299 | CD | GLN | D | 119 | −1.177 | 72.721 | 17.757 | 1.00 | 44.44 | D | C |
| ATOM | 5300 | OE1 | GLN | D | 119 | −0.374 | 73.149 | 16.919 | 1.00 | 43.73 | D | O |
| ATOM | 5301 | NE2 | GLN | D | 119 | −2.289 | 72.068 | 17.420 | 1.00 | 42.08 | D | N |
| ATOM | 5302 | C | GLN | D | 119 | 1.266 | 72.384 | 21.527 | 1.00 | 23.39 | D | C |
| ATOM | 5303 | O | GLN | D | 119 | 1.414 | 73.601 | 21.623 | 1.00 | 24.72 | D | O |
| ATOM | 5304 | N | ILE | D | 120 | 2.267 | 71.517 | 21.545 | 1.00 | 20.10 | D | N |
| ATOM | 5305 | CA | ILE | D | 120 | 3.645 | 71.927 | 21.683 | 1.00 | 19.98 | D | C |
| ATOM | 5306 | CB | ILE | D | 120 | 4.380 | 71.030 | 22.704 | 1.00 | 19.22 | D | C |
| ATOM | 5307 | CG2 | ILE | D | 120 | 5.776 | 71.572 | 22.970 | 1.00 | 13.68 | D | C |
| ATOM | 5308 | CG1 | ILE | D | 120 | 3.560 | 70.929 | 23.993 | 1.00 | 14.39 | D | C |
| ATOM | 5309 | CD1 | ILE | D | 120 | 3.174 | 72.270 | 24.577 | 1.00 | 13.00 | D | C |
| ATOM | 5310 | C | ILE | D | 120 | 4.352 | 71.825 | 20.346 | 1.00 | 22.26 | D | C |
| ATOM | 5311 | O | ILE | D | 120 | 4.302 | 70.787 | 19.682 | 1.00 | 23.25 | D | O |
| ATOM | 5312 | N | THR | D | 121 | 5.010 | 72.910 | 19.955 | 1.00 | 23.62 | D | N |
| ATOM | 5313 | CA | THR | D | 121 | 5.746 | 72.951 | 18.703 | 1.00 | 24.64 | D | C |
| ATOM | 5314 | CB | THR | D | 121 | 5.584 | 74.315 | 18.004 | 1.00 | 22.22 | D | C |
| ATOM | 5315 | OG1 | THR | D | 121 | 6.329 | 75.304 | 18.715 | 1.00 | 21.82 | D | O |
| ATOM | 5316 | CG2 | THR | D | 121 | 4.122 | 74.730 | 17.961 | 1.00 | 22.20 | D | C |
| ATOM | 5317 | C | THR | D | 121 | 7.220 | 72.715 | 18.997 | 1.00 | 25.56 | D | C |
| ATOM | 5318 | O | THR | D | 121 | 7.676 | 72.943 | 20.110 | 1.00 | 29.83 | D | O |
| ATOM | 5319 | N | GLY | D | 122 | 7.959 | 72.245 | 18.004 | 1.00 | 28.32 | D | N |
| ATOM | 5320 | CA | GLY | D | 122 | 9.375 | 71.999 | 18.193 | 1.00 | 30.65 | D | C |
| ATOM | 5321 | C | GLY | D | 122 | 9.723 | 70.539 | 18.402 | 1.00 | 35.69 | D | C |
| ATOM | 5322 | O | GLY | D | 122 | 8.847 | 69.701 | 18.611 | 1.00 | 34.08 | D | O |
| ATOM | 5323 | N | ASP | D | 123 | 11.018 | 70.241 | 18.345 | 1.00 | 40.99 | D | N |
| ATOM | 5324 | CA | ASP | D | 123 | 11.515 | 68.881 | 18.528 | 1.00 | 45.31 | D | C |
| ATOM | 5325 | CB | ASP | D | 123 | 12.871 | 68.710 | 17.839 | 1.00 | 48.95 | D | C |
| ATOM | 5326 | CG | ASP | D | 123 | 12.784 | 68.874 | 16.339 | 1.00 | 53.70 | D | C |
| ATOM | 5327 | OD1 | ASP | D | 123 | 11.906 | 68.227 | 15.724 | 1.00 | 54.96 | D | O |
| ATOM | 5328 | OD2 | ASP | D | 123 | 13.592 | 69.650 | 15.776 | 1.00 | 55.96 | D | O |
| ATOM | 5329 | C | ASP | D | 123 | 11.674 | 68.570 | 20.004 | 1.00 | 45.06 | D | C |
| ATOM | 5330 | O | ASP | D | 123 | 12.255 | 69.360 | 20.755 | 1.00 | 46.02 | D | O |
| ATOM | 5331 | N | TYR | D | 124 | 11.164 | 67.414 | 20.416 | 1.00 | 44.10 | D | N |
| ATOM | 5332 | CA | TYR | D | 124 | 11.262 | 67.010 | 21.809 | 1.00 | 40.82 | D | C |
| ATOM | 5333 | CB | TYR | D | 124 | 10.288 | 65.868 | 22.093 | 1.00 | 37.81 | D | C |
| ATOM | 5334 | CG | TYR | D | 124 | 8.922 | 66.346 | 22.527 | 1.00 | 36.53 | D | C |
| ATOM | 5335 | CD1 | TYR | D | 124 | 7.922 | 66.605 | 21.590 | 1.00 | 34.18 | D | C |
| ATOM | 5336 | CE1 | TYR | D | 124 | 6.664 | 67.075 | 21.986 | 1.00 | 34.11 | D | C |
| ATOM | 5337 | CD2 | TYR | D | 124 | 8.636 | 66.566 | 23.876 | 1.00 | 32.17 | D | C |
| ATOM | 5338 | CE2 | TYR | D | 124 | 7.387 | 67.033 | 24.278 | 1.00 | 31.73 | D | C |
| ATOM | 5339 | CZ | TYR | D | 124 | 6.407 | 67.287 | 23.330 | 1.00 | 31.73 | D | C |
| ATOM | 5340 | OH | TYR | D | 124 | 5.179 | 67.761 | 23.724 | 1.00 | 29.38 | D | O |
| ATOM | 5341 | C | TYR | D | 124 | 12.688 | 66.582 | 22.131 | 1.00 | 41.04 | D | C |
| ATOM | 5342 | O | TYR | D | 124 | 13.235 | 65.739 | 21.390 | 1.00 | 41.92 | D | O |
| ATOM | 5343 | OT | TYR | D | 124 | 13.248 | 67.108 | 23.114 | 1.00 | 43.41 | D | O |
| ATOM | 5344 | CB | ASP | E | 132 | 20.519 | 59.150 | 27.205 | 1.00 | 53.53 | E | C |
| ATOM | 5345 | CG | ASP | E | 132 | 20.156 | 59.474 | 28.646 | 1.00 | 57.07 | E | C |
| ATOM | 5346 | OD1 | ASP | E | 132 | 19.149 | 60.188 | 28.862 | 1.00 | 57.02 | E | O |
| ATOM | 5347 | OD2 | ASP | E | 132 | 20.881 | 59.014 | 29.562 | 1.00 | 58.30 | E | O |
| ATOM | 5348 | C | ASP | E | 132 | 18.473 | 57.761 | 26.853 | 1.00 | 47.10 | E | C |
| ATOM | 5349 | O | ASP | E | 132 | 17.899 | 57.058 | 27.682 | 1.00 | 47.32 | E | O |
| ATOM | 5350 | N | ASP | E | 132 | 20.416 | 57.503 | 25.350 | 1.00 | 48.89 | E | N |
| ATOM | 5351 | CA | ASP | E | 132 | 19.992 | 57.783 | 26.756 | 1.00 | 49.69 | E | C |
| ATOM | 5352 | N | PHE | E | 133 | 17.829 | 58.549 | 26.000 | 1.00 | 46.73 | E | N |
| ATOM | 5353 | CA | PHE | E | 133 | 16.374 | 58.609 | 25.959 | 1.00 | 44.88 | E | C |
| ATOM | 5354 | CB | PHE | E | 133 | 15.920 | 59.772 | 25.069 | 1.00 | 42.16 | E | C |
| ATOM | 5355 | CG | PHE | E | 133 | 14.431 | 59.865 | 24.899 | 1.00 | 41.07 | E | C |
| ATOM | 5356 | CD1 | PHE | E | 133 | 13.873 | 60.025 | 23.632 | 1.00 | 40.54 | E | C |
| ATOM | 5357 | CD2 | PHE | E | 133 | 13.581 | 59.786 | 26.004 | 1.00 | 41.11 | E | C |
| ATOM | 5358 | CE1 | PHE | E | 133 | 12.488 | 60.105 | 23.463 | 1.00 | 41.86 | E | C |
| ATOM | 5359 | CE2 | PHE | E | 133 | 12.195 | 59.864 | 25.854 | 1.00 | 40.43 | E | C |
| ATOM | 5360 | CZ | PHE | E | 133 | 11.644 | 60.024 | 24.580 | 1.00 | 42.47 | E | C |
| ATOM | 5361 | C | PHE | E | 133 | 15.899 | 57.285 | 25.369 | 1.00 | 45.13 | E | C |
| ATOM | 5362 | O | PHE | E | 133 | 14.790 | 56.823 | 25.645 | 1.00 | 44.81 | E | O |
| ATOM | 5363 | N | GLU | E | 134 | 16.762 | 56.682 | 24.558 | 1.00 | 42.31 | E | N |
| ATOM | 5364 | CA | GLU | E | 134 | 16.463 | 55.416 | 23.916 | 1.00 | 41.29 | E | C |
| ATOM | 5365 | CB | GLU | E | 134 | 17.625 | 55.007 | 23.008 | 1.00 | 45.93 | E | C |
| ATOM | 5366 | CG | GLU | E | 134 | 17.212 | 54.676 | 21.579 | 1.00 | 53.20 | E | C |
| ATOM | 5367 | CD | GLU | E | 134 | 17.624 | 53.274 | 21.162 | 1.00 | 56.59 | E | C |
| ATOM | 5368 | OE1 | GLU | E | 134 | 18.795 | 52.904 | 21.401 | 1.00 | 59.31 | E | O |
| ATOM | 5369 | OE2 | GLU | E | 134 | 16.778 | 52.545 | 20.597 | 1.00 | 57.19 | E | O |
| ATOM | 5370 | C | GLU | E | 134 | 16.230 | 54.340 | 24.965 | 1.00 | 39.42 | E | C |
| ATOM | 5371 | O | GLU | E | 134 | 15.275 | 53.561 | 24.879 | 1.00 | 36.85 | E | O |
| ATOM | 5372 | N | ILE | E | 135 | 17.110 | 54.298 | 25.958 | 1.00 | 36.66 | E | N |
| ATOM | 5373 | CA | ILE | E | 135 | 16.996 | 53.301 | 27.008 | 1.00 | 35.46 | E | C |
| ATOM | 5374 | CB | ILE | E | 135 | 18.273 | 53.259 | 27.889 | 1.00 | 37.66 | E | C |
| ATOM | 5375 | CG2 | ILE | E | 135 | 19.514 | 53.500 | 27.027 | 1.00 | 36.42 | E | C |
| ATOM | 5376 | CG1 | ILE | E | 135 | 18.179 | 54.296 | 29.008 | 1.00 | 41.31 | E | C |
| ATOM | 5377 | CD1 | ILE | E | 135 | 17.920 | 53.687 | 30.379 | 1.00 | 44.66 | E | C |
| ATOM | 5378 | C | ILE | E | 135 | 15.777 | 53.562 | 27.877 | 1.00 | 32.02 | E | C |
| ATOM | 5379 | O | ILE | E | 135 | 15.195 | 52.632 | 28.438 | 1.00 | 32.24 | E | O |
| ATOM | 5380 | N | VAL | E | 136 | 15.389 | 54.826 | 27.991 | 1.00 | 28.45 | E | N |
| ATOM | 5381 | CA | VAL | E | 136 | 14.224 | 55.167 | 28.792 | 1.00 | 26.24 | E | C |
| ATOM | 5382 | CB | VAL | E | 136 | 14.083 | 56.699 | 28.978 | 1.00 | 25.78 | E | C |
| ATOM | 5383 | CG1 | VAL | E | 136 | 12.743 | 57.027 | 29.602 | 1.00 | 23.91 | E | C |
| ATOM | 5384 | CG2 | VAL | E | 136 | 15.204 | 57.226 | 29.849 | 1.00 | 21.09 | E | C |
| ATOM | 5385 | C | VAL | E | 136 | 12.999 | 54.637 | 28.061 | 1.00 | 25.58 | E | C |
| ATOM | 5386 | O | VAL | E | 136 | 12.143 | 53.981 | 28.649 | 1.00 | 24.96 | E | O |
| ATOM | 5387 | N | CYS | E | 137 | 12.929 | 54.919 | 26.765 | 1.00 | 26.30 | E | N |
| ATOM | 5388 | CA | CYS | E | 137 | 11.807 | 54.473 | 25.947 | 1.00 | 24.10 | E | C |
| ATOM | 5389 | CB | CYS | E | 137 | 11.928 | 55.053 | 24.538 | 1.00 | 23.46 | E | C |
| ATOM | 5390 | SG | CYS | E | 137 | 11.383 | 56.787 | 24.404 | 1.00 | 24.83 | E | S |
| ATOM | 5391 | C | CYS | E | 137 | 11.746 | 52.955 | 25.896 | 1.00 | 21.87 | E | C |
| ATOM | 5392 | O | CYS | E | 137 | 10.666 | 52.371 | 25.888 | 1.00 | 23.29 | E | O |
| ATOM | 5393 | N | LYS | E | 138 | 12.908 | 52.316 | 25.869 | 1.00 | 21.81 | E | N |
| ATOM | 5394 | CA | LYS | E | 138 | 12.970 | 50.861 | 25.830 | 1.00 | 24.11 | E | C |
| ATOM | 5395 | CB | LYS | E | 138 | 14.413 | 50.391 | 25.652 | 1.00 | 28.52 | E | C |
| ATOM | 5396 | CG | LYS | E | 138 | 14.846 | 50.221 | 24.210 | 1.00 | 36.45 | E | C |
| ATOM | 5397 | CD | LYS | E | 138 | 16.333 | 49.897 | 24.136 | 1.00 | 42.80 | E | C |
| ATOM | 5398 | CE | LYS | E | 138 | 16.858 | 49.989 | 22.713 | 1.00 | 45.35 | E | C |
| ATOM | 5399 | NZ | LYS | E | 138 | 17.507 | 48.708 | 22.301 | 1.00 | 49.51 | E | N |
| ATOM | 5400 | C | LYS | E | 138 | 12.416 | 50.280 | 27.127 | 1.00 | 23.75 | E | C |
| ATOM | 5401 | O | LYS | E | 138 | 11.677 | 49.291 | 27.107 | 1.00 | 25.68 | E | O |
| ATOM | 5402 | N | GLY | E | 139 | 12.786 | 50.894 | 28.251 | 1.00 | 21.86 | E | N |
| ATOM | 5403 | CA | GLY | E | 139 | 12.322 | 50.438 | 29.553 | 1.00 | 18.28 | E | C |
| ATOM | 5404 | C | GLY | E | 139 | 10.814 | 50.552 | 29.708 | 1.00 | 18.61 | E | C |
| ATOM | 5405 | O | GLY | E | 139 | 10.154 | 49.623 | 30.173 | 1.00 | 18.96 | E | O |
| ATOM | 5406 | N | LEU | E | 140 | 10.260 | 51.693 | 29.315 | 1.00 | 17.96 | E | N |
| ATOM | 5407 | CA | LEU | E | 140 | 8.823 | 51.911 | 29.416 | 1.00 | 18.26 | E | C |
| ATOM | 5408 | CB | LEU | E | 140 | 8.487 | 53.353 | 29.030 | 1.00 | 18.94 | E | C |
| ATOM | 5409 | CG | LEU | E | 140 | 8.984 | 54.398 | 30.036 | 1.00 | 17.37 | E | C |
| ATOM | 5410 | CD1 | LEU | E | 140 | 8.759 | 55.807 | 29.506 | 1.00 | 17.09 | E | C |
| ATOM | 5411 | CD2 | LEU | E | 140 | 8.255 | 54.208 | 31.344 | 1.00 | 12.92 | E | C |
| ATOM | 5412 | C | LEU | E | 140 | 8.063 | 50.937 | 28.524 | 1.00 | 19.68 | E | C |
| ATOM | 5413 | O | LEU | E | 140 | 6.980 | 50.468 | 28.884 | 1.00 | 20.91 | E | O |
| ATOM | 5414 | N | TYR | E | 141 | 8.635 | 50.624 | 27.365 | 1.00 | 18.89 | E | N |
| ATOM | 5415 | CA | TYR | E | 141 | 7.998 | 49.697 | 26.442 | 1.00 | 16.02 | E | C |
| ATOM | 5416 | CB | TYR | E | 141 | 8.756 | 49.668 | 25.108 | 1.00 | 17.39 | E | C |
| ATOM | 5417 | CG | TYR | E | 141 | 8.536 | 48.405 | 24.305 | 1.00 | 14.32 | E | C |
| ATOM | 5418 | CD1 | TYR | E | 141 | 9.470 | 47.373 | 24.330 | 1.00 | 14.83 | E | C |
| ATOM | 5419 | CE1 | TYR | E | 141 | 9.246 | 46.183 | 23.642 | 1.00 | 20.81 | E | C |
| ATOM | 5420 | CD2 | TYR | E | 141 | 7.371 | 48.223 | 23.562 | 1.00 | 14.55 | E | C |
| ATOM | 5421 | CE2 | TYR | E | 141 | 7.135 | 47.039 | 22.870 | 1.00 | 18.31 | E | C |
| ATOM | 5422 | CZ | TYR | E | 141 | 8.074 | 46.022 | 22.916 | 1.00 | 21.92 | E | C |
| ATOM | 5423 | OH | TYR | E | 141 | 7.834 | 44.832 | 22.259 | 1.00 | 27.23 | E | O |
| ATOM | 5424 | C | TYR | E | 141 | 7.976 | 48.303 | 27.060 | 1.00 | 16.40 | E | C |
| ATOM | 5425 | O | TYR | E | 141 | 6.926 | 47.657 | 27.138 | 1.00 | 14.76 | E | O |
| ATOM | 5426 | N | ARG | E | 142 | 9.137 | 47.839 | 27.510 | 1.00 | 16.16 | E | N |
| ATOM | 5427 | CA | ARG | E | 142 | 9.223 | 46.516 | 28.102 | 1.00 | 17.11 | E | C |
| ATOM | 5428 | CB | ARG | E | 142 | 10.671 | 46.203 | 28.478 | 1.00 | 16.83 | E | C |
| ATOM | 5429 | CG | ARG | E | 142 | 10.799 | 45.103 | 29.514 | 1.00 | 24.49 | E | C |
| ATOM | 5430 | CD | ARG | E | 142 | 11.994 | 44.180 | 29.296 | 1.00 | 24.80 | E | C |
| ATOM | 5431 | NE | ARG | E | 142 | 11.824 | 42.955 | 30.081 | 1.00 | 30.66 | E | N |
| ATOM | 5432 | CZ | ARG | E | 142 | 12.798 | 42.332 | 30.737 | 1.00 | 31.73 | E | C |
| ATOM | 5433 | NH1 | ARG | E | 142 | 14.036 | 42.822 | 30.708 | 1.00 | 29.35 | E | N |
| ATOM | 5434 | NH2 | ARG | E | 142 | 12.528 | 41.232 | 31.440 | 1.00 | 27.60 | E | N |
| ATOM | 5435 | C | ARG | E | 142 | 8.311 | 46.401 | 29.328 | 1.00 | 18.52 | E | C |
| ATOM | 5436 | O | ARG | E | 142 | 7.720 | 45.347 | 29.576 | 1.00 | 20.49 | E | O |
| ATOM | 5437 | N | ALA | E | 143 | 8.186 | 47.486 | 30.087 | 1.00 | 17.31 | E | N |
| ATOM | 5438 | CA | ALA | E | 143 | 7.339 | 47.484 | 31.281 | 1.00 | 16.40 | E | C |
| ATOM | 5439 | CB | ALA | E | 143 | 7.507 | 48.787 | 32.052 | 1.00 | 16.88 | E | C |
| ATOM | 5440 | C | ALA | E | 143 | 5.880 | 47.286 | 30.918 | 1.00 | 15.39 | E | C |
| ATOM | 5441 | O | ALA | E | 143 | 5.156 | 46.584 | 31.617 | 1.00 | 16.44 | E | O |
| ATOM | 5442 | N | LEU | E | 144 | 5.449 | 47.909 | 29.827 | 1.00 | 14.91 | E | N |
| ATOM | 5443 | CA | LEU | E | 144 | 4.065 | 47.782 | 29.377 | 1.00 | 16.74 | E | C |
| ATOM | 5444 | CB | LEU | E | 144 | 3.752 | 48.839 | 28.319 | 1.00 | 15.48 | E | C |
| ATOM | 5445 | CG | LEU | E | 144 | 3.490 | 50.241 | 28.869 | 1.00 | 15.14 | E | C |
| ATOM | 5446 | CD1 | LEU | E | 144 | 3.398 | 51.248 | 27.744 | 1.00 | 10.74 | E | C |
| ATOM | 5447 | CD2 | LEU | E | 144 | 2.208 | 50.212 | 29.671 | 1.00 | 13.20 | E | C |
| ATOM | 5448 | C | LEU | E | 144 | 3.829 | 46.394 | 28.801 | 1.00 | 16.96 | E | C |
| ATOM | 5449 | O | LEU | E | 144 | 2.716 | 45.868 | 28.841 | 1.00 | 17.59 | E | O |
| ATOM | 5450 | N | CYS | E | 145 | 4.888 | 45.804 | 28.264 | 1.00 | 19.25 | E | N |
| ATOM | 5451 | CA | CYS | E | 145 | 4.815 | 44.472 | 27.683 | 1.00 | 18.12 | E | C |
| ATOM | 5452 | CB | CYS | E | 145 | 6.108 | 44.149 | 26.949 | 1.00 | 22.70 | E | C |
| ATOM | 5453 | SG | CYS | E | 145 | 5.972 | 44.312 | 25.186 | 1.00 | 35.92 | E | S |
| ATOM | 5454 | C | CYS | E | 145 | 4.615 | 43.447 | 28.774 | 1.00 | 16.33 | E | C |
| ATOM | 5455 | O | CYS | E | 145 | 3.902 | 42.459 | 28.590 | 1.00 | 17.97 | E | O |
| ATOM | 5456 | N | ILE | E | 146 | 5.267 | 43.682 | 29.907 | 1.00 | 15.11 | E | N |
| ATOM | 5457 | CA | ILE | E | 146 | 5.182 | 42.785 | 31.048 | 1.00 | 12.24 | E | C |
| ATOM | 5458 | CB | ILE | E | 146 | 6.202 | 43.182 | 32.139 | 1.00 | 11.99 | E | C |
| ATOM | 5459 | CG2 | ILE | E | 146 | 5.870 | 42.487 | 33.450 | 1.00 | 13.24 | E | C |
| ATOM | 5460 | CG1 | ILE | E | 146 | 7.612 | 42.796 | 31.692 | 1.00 | 9.07 | E | C |
| ATOM | 5461 | CD1 | ILE | E | 146 | 8.705 | 43.568 | 32.384 | 1.00 | 9.16 | E | C |
| ATOM | 5462 | C | ILE | E | 146 | 3.778 | 42.780 | 31.643 | 1.00 | 12.98 | E | C |
| ATOM | 5463 | O | ILE | E | 146 | 3.232 | 41.715 | 31.938 | 1.00 | 14.51 | E | O |
| ATOM | 5464 | N | ARG | E | 147 | 3.178 | 43.955 | 31.809 | 1.00 | 12.07 | E | N |
| ATOM | 5465 | CA | ARG | E | 147 | 1.836 | 43.999 | 32.380 | 1.00 | 11.87 | E | C |
| ATOM | 5466 | CB | ARG | E | 147 | 1.392 | 45.431 | 32.662 | 1.00 | 9.61 | E | C |
| ATOM | 5467 | CG | ARG | E | 147 | −0.084 | 45.500 | 33.036 | 1.00 | 7.57 | E | C |
| ATOM | 5468 | CD | ARG | E | 147 | −0.468 | 46.808 | 33.681 | 1.00 | 7.05 | E | C |
| ATOM | 5469 | NE | ARG | E | 147 | −1.883 | 46.835 | 34.047 | 1.00 | 7.28 | E | N |
| ATOM | 5470 | CZ | ARG | E | 147 | −2.386 | 46.260 | 35.138 | 1.00 | 8.84 | E | C |
| ATOM | 5471 | NH1 | ARG | E | 147 | −1.591 | 45.604 | 35.975 | 1.00 | 6.36 | E | N |
| ATOM | 5472 | NH2 | ARG | E | 147 | −3.682 | 46.360 | 35.403 | 1.00 | 5.11 | E | N |
| ATOM | 5473 | C | ARG | E | 147 | 0.826 | 43.344 | 31.452 | 1.00 | 15.63 | E | C |
| ATOM | 5474 | O | ARG | E | 147 | −0.106 | 42.667 | 31.903 | 1.00 | 16.00 | E | O |
| ATOM | 5475 | N | GLU | E | 148 | 0.999 | 43.557 | 30.150 | 1.00 | 17.37 | E | N |
| ATOM | 5476 | CA | GLU | E | 148 | 0.096 | 42.962 | 29.168 | 1.00 | 17.49 | E | C |
| ATOM | 5477 | CB | GLU | E | 148 | 0.422 | 43.482 | 27.771 | 1.00 | 19.01 | E | C |
| ATOM | 5478 | CG | GLU | E | 148 | −0.413 | 42.848 | 26.668 | 1.00 | 21.75 | E | C |
| ATOM | 5479 | CD | GLU | E | 148 | 0.162 | 43.114 | 25.298 | 1.00 | 23.52 | E | C |
| ATOM | 5480 | OE1 | GLU | E | 148 | −0.542 | 43.717 | 24.459 | 1.00 | 25.37 | E | O |
| ATOM | 5481 | OE2 | GLU | E | 148 | 1.323 | 42.722 | 25.064 | 1.00 | 24.86 | E | O |
| ATOM | 5482 | C | GLU | E | 148 | 0.216 | 41.439 | 29.180 | 1.00 | 16.64 | E | C |
| ATOM | 5483 | O | GLU | E | 148 | −0.791 | 40.722 | 29.126 | 1.00 | 16.41 | E | O |
| ATOM | 5484 | N | LYS | E | 149 | 1.451 | 40.946 | 29.255 | 1.00 | 15.22 | E | N |
| ATOM | 5485 | CA | LYS | E | 149 | 1.686 | 39.508 | 29.268 | 1.00 | 15.21 | E | C |
| ATOM | 5486 | CB | LYS | E | 149 | 3.185 | 39.221 | 29.334 | 1.00 | 12.64 | E | C |
| ATOM | 5487 | CG | LYS | E | 149 | 3.532 | 37.742 | 29.388 | 1.00 | 12.61 | E | C |
| ATOM | 5488 | CD | LYS | E | 149 | 5.035 | 37.521 | 29.342 | 1.00 | 13.17 | E | C |
| ATOM | 5489 | CE | LYS | E | 149 | 5.717 | 38.042 | 30.598 | 1.00 | 15.32 | E | C |
| ATOM | 5490 | NZ | LYS | E | 149 | 7.195 | 37.786 | 30.580 | 1.00 | 16.82 | E | N |
| ATOM | 5491 | C | LYS | E | 149 | 0.976 | 38.819 | 30.430 | 1.00 | 18.80 | E | C |
| ATOM | 5492 | O | LYS | E | 149 | 0.256 | 37.836 | 30.228 | 1.00 | 19.30 | E | O |
| ATOM | 5493 | N | TYR | E | 150 | 1.165 | 39.345 | 31.641 | 1.00 | 17.83 | E | N |
| ATOM | 5494 | CA | TYR | E | 150 | 0.555 | 38.766 | 32.829 | 1.00 | 14.47 | E | C |
| ATOM | 5495 | CB | TYR | E | 150 | 1.260 | 39.308 | 34.077 | 1.00 | 19.32 | E | C |
| ATOM | 5496 | CG | TYR | E | 150 | 2.683 | 38.795 | 34.213 | 1.00 | 18.38 | E | C |
| ATOM | 5497 | CD1 | TYR | E | 150 | 2.930 | 37.466 | 34.559 | 1.00 | 18.84 | E | C |
| ATOM | 5498 | CE1 | TYR | E | 150 | 4.232 | 36.954 | 34.603 | 1.00 | 18.37 | E | C |
| ATOM | 5499 | CD2 | TYR | E | 150 | 3.779 | 39.611 | 33.921 | 1.00 | 17.49 | E | C |
| ATOM | 5500 | CE2 | TYR | E | 150 | 5.090 | 39.105 | 33.964 | 1.00 | 18.66 | E | C |
| ATOM | 5501 | CZ | TYR | E | 150 | 5.301 | 37.775 | 34.304 | 1.00 | 17.35 | E | C |
| ATOM | 5502 | OH | TYR | E | 150 | 6.571 | 37.250 | 34.329 | 1.00 | 20.05 | E | O |
| ATOM | 5503 | C | TYR | E | 150 | −0.949 | 38.996 | 32.909 | 1.00 | 14.99 | E | C |
| ATOM | 5504 | O | TYR | E | 150 | −1.665 | 38.211 | 33.532 | 1.00 | 15.90 | E | O |
| ATOM | 5505 | N | MET | E | 151 | −1.441 | 40.058 | 32.279 | 1.00 | 14.51 | E | N |
| ATOM | 5506 | CA | MET | E | 151 | −2.879 | 40.327 | 32.300 | 1.00 | 15.67 | E | C |
| ATOM | 5507 | CB | MET | E | 151 | −3.171 | 41.757 | 31.843 | 1.00 | 13.46 | E | C |
| ATOM | 5508 | CG | MET | E | 151 | −2.828 | 42.835 | 32.859 | 1.00 | 14.86 | E | C |
| ATOM | 5509 | SD | MET | E | 151 | −3.692 | 42.671 | 34.446 | 1.00 | 13.02 | E | S |
| ATOM | 5510 | CE | MET | E | 151 | −2.374 | 41.998 | 35.441 | 1.00 | 7.32 | E | C |
| ATOM | 5511 | C | MET | E | 151 | −3.659 | 39.350 | 31.411 | 1.00 | 17.29 | E | C |
| ATOM | 5512 | O | MET | E | 151 | −4.670 | 38.795 | 31.832 | 1.00 | 21.28 | E | O |
| ATOM | 5513 | N | LEU | E | 152 | −3.196 | 39.138 | 30.183 | 1.00 | 18.99 | E | N |
| ATOM | 5514 | CA | LEU | E | 152 | −3.884 | 38.231 | 29.261 | 1.00 | 19.60 | E | C |
| ATOM | 5515 | CB | LEU | E | 152 | −3.338 | 38.389 | 27.843 | 1.00 | 20.29 | E | C |
| ATOM | 5516 | CG | LEU | E | 152 | −3.325 | 39.802 | 27.249 | 1.00 | 26.20 | E | C |
| ATOM | 5517 | CD1 | LEU | E | 152 | −2.912 | 39.711 | 25.789 | 1.00 | 25.81 | E | C |
| ATOM | 5518 | CD2 | LEU | E | 152 | −4.708 | 40.464 | 27.385 | 1.00 | 26.84 | E | C |
| ATOM | 5519 | C | LEU | E | 152 | −3.730 | 36.783 | 29.687 | 1.00 | 17.83 | E | C |
| ATOM | 5520 | O | LEU | E | 152 | −4.643 | 35.971 | 29.539 | 1.00 | 18.53 | E | O |
| ATOM | 5521 | N | LYS | E | 153 | −2.556 | 36.468 | 30.213 | 1.00 | 17.65 | E | N |
| ATOM | 5522 | CA | LYS | E | 153 | −2.246 | 35.126 | 30.668 | 1.00 | 19.42 | E | C |
| ATOM | 5523 | CB | LYS | E | 153 | −0.775 | 35.076 | 31.070 | 1.00 | 21.51 | E | C |
| ATOM | 5524 | CG | LYS | E | 153 | −0.358 | 33.878 | 31.877 | 1.00 | 25.20 | E | C |
| ATOM | 5525 | CD | LYS | E | 153 | 1.043 | 34.091 | 32.431 | 1.00 | 27.01 | E | C |
| ATOM | 5526 | CE | LYS | E | 153 | 2.030 | 34.323 | 31.308 | 1.00 | 30.19 | E | C |
| ATOM | 5527 | NZ | LYS | E | 153 | 3.430 | 34.357 | 31.814 | 1.00 | 36.43 | E | N |
| ATOM | 5528 | C | LYS | E | 153 | −3.144 | 34.686 | 31.830 | 1.00 | 20.59 | E | C |
| ATOM | 5529 | O | LYS | E | 153 | −3.319 | 33.489 | 32.061 | 1.00 | 19.40 | E | O |
| ATOM | 5530 | N | SER | E | 154 | −3.721 | 35.650 | 32.550 | 1.00 | 19.81 | E | N |
| ATOM | 5531 | CA | SER | E | 154 | −4.591 | 35.339 | 33.681 | 1.00 | 19.27 | E | C |
| ATOM | 5532 | CB | SER | E | 154 | −4.079 | 36.016 | 34.951 | 1.00 | 18.46 | E | C |
| ATOM | 5533 | OG | SER | E | 154 | −4.147 | 37.427 | 34.833 | 1.00 | 21.11 | E | O |
| ATOM | 5534 | C | SER | E | 154 | −6.037 | 35.752 | 33.439 | 1.00 | 22.40 | E | C |
| ATOM | 5535 | O | SER | E | 154 | −6.866 | 35.707 | 34.358 | 1.00 | 21.57 | E | O |
| ATOM | 5536 | N | PHE | E | 155 | −6.332 | 36.158 | 32.206 | 1.00 | 18.51 | E | N |
| ATOM | 5537 | CA | PHE | E | 155 | −7.680 | 36.565 | 31.826 | 1.00 | 17.10 | E | C |
| ATOM | 5538 | CB | PHE | E | 155 | −8.660 | 35.419 | 32.071 | 1.00 | 20.88 | E | C |
| ATOM | 5539 | CG | PHE | E | 155 | −8.371 | 34.208 | 31.244 | 1.00 | 25.46 | E | C |
| ATOM | 5540 | CD1 | PHE | E | 155 | −8.925 | 34.068 | 29.978 | 1.00 | 26.29 | E | C |
| ATOM | 5541 | CD2 | PHE | E | 155 | −7.487 | 33.233 | 31.703 | 1.00 | 27.05 | E | C |
| ATOM | 5542 | CE1 | PHE | E | 155 | −8.595 | 32.974 | 29.176 | 1.00 | 29.46 | E | C |
| ATOM | 5543 | CE2 | PHE | E | 155 | −7.150 | 32.133 | 30.906 | 1.00 | 26.11 | E | C |
| ATOM | 5544 | CZ | PHE | E | 155 | −7.703 | 32.007 | 29.645 | 1.00 | 27.46 | E | C |
| ATOM | 5545 | C | PHE | E | 155 | −8.160 | 37.820 | 32.529 | 1.00 | 16.58 | E | C |
| ATOM | 5546 | O | PHE | E | 155 | −9.335 | 37.944 | 32.882 | 1.00 | 17.12 | E | O |
| ATOM | 5547 | N | GLN | E | 156 | −7.245 | 38.758 | 32.730 | 1.00 | 14.45 | E | N |
| ATOM | 5548 | CA | GLN | E | 156 | −7.599 | 40.014 | 33.359 | 1.00 | 14.25 | E | C |
| ATOM | 5549 | CB | GLN | E | 156 | −6.652 | 40.304 | 34.522 | 1.00 | 12.97 | E | C |
| ATOM | 5550 | CG | GLN | E | 156 | −6.862 | 39.348 | 35.691 | 1.00 | 10.23 | E | C |
| ATOM | 5551 | CD | GLN | E | 156 | −6.205 | 39.817 | 36.965 | 1.00 | 11.97 | E | C |
| ATOM | 5552 | OE1 | GLN | E | 156 | −5.023 | 39.551 | 37.205 | 1.00 | 13.97 | E | O |
| ATOM | 5553 | NE2 | GLN | E | 156 | −6.963 | 40.516 | 37.794 | 1.00 | 8.24 | E | N |
| ATOM | 5554 | C | GLN | E | 156 | −7.522 | 41.071 | 32.267 | 1.00 | 15.59 | E | C |
| ATOM | 5555 | O | GLN | E | 156 | −6.980 | 40.807 | 31.192 | 1.00 | 16.60 | E | O |
| ATOM | 5556 | N | ARG | E | 157 | −8.062 | 42.258 | 32.531 | 1.00 | 16.21 | E | N |
| ATOM | 5557 | CA | ARG | E | 157 | −8.104 | 43.317 | 31.527 | 1.00 | 14.91 | E | C |
| ATOM | 5558 | CB | ARG | E | 157 | −9.294 | 44.236 | 31.820 | 1.00 | 12.81 | E | C |
| ATOM | 5559 | CG | ARG | E | 157 | −10.579 | 43.477 | 32.124 | 1.00 | 12.92 | E | C |
| ATOM | 5560 | CD | ARG | E | 157 | −11.681 | 44.401 | 32.631 | 1.00 | 12.91 | E | C |
| ATOM | 5561 | NE | ARG | E | 157 | −11.419 | 44.849 | 33.996 | 1.00 | 15.58 | E | N |
| ATOM | 5562 | CZ | ARG | E | 157 | −12.221 | 45.645 | 34.696 | 1.00 | 12.97 | E | C |
| ATOM | 5563 | NH1 | ARG | E | 157 | −11.892 | 45.995 | 35.929 | 1.00 | 15.11 | E | N |
| ATOM | 5564 | NH2 | ARG | E | 157 | −13.351 | 46.087 | 34.171 | 1.00 | 12.70 | E | N |
| ATOM | 5565 | C | ARG | E | 157 | −6.867 | 44.175 | 31.286 | 1.00 | 14.85 | E | C |
| ATOM | 5566 | O | ARG | E | 157 | −6.123 | 44.502 | 32.207 | 1.00 | 16.83 | E | O |
| ATOM | 5567 | N | PHE | E | 158 | −6.672 | 44.523 | 30.013 | 1.00 | 15.97 | E | N |
| ATOM | 5568 | CA | PHE | E | 158 | −5.595 | 45.395 | 29.545 | 1.00 | 13.15 | E | C |
| ATOM | 5569 | CB | PHE | E | 158 | −4.376 | 44.599 | 29.099 | 1.00 | 9.14 | E | C |
| ATOM | 5570 | CG | PHE | E | 158 | −3.151 | 45.448 | 28.923 | 1.00 | 11.98 | E | C |
| ATOM | 5571 | CD1 | PHE | E | 158 | −2.704 | 45.798 | 27.653 | 1.00 | 9.48 | E | C |
| ATOM | 5572 | CD2 | PHE | E | 158 | −2.477 | 45.946 | 30.027 | 1.00 | 6.78 | E | C |
| ATOM | 5573 | CE1 | PHE | E | 158 | −1.608 | 46.635 | 27.486 | 1.00 | 6.97 | E | C |
| ATOM | 5574 | CE2 | PHE | E | 158 | −1.385 | 46.779 | 29.870 | 1.00 | 8.87 | E | C |
| ATOM | 5575 | CZ | PHE | E | 158 | −0.949 | 47.126 | 28.590 | 1.00 | 10.45 | E | C |
| ATOM | 5576 | C | PHE | E | 158 | −6.172 | 46.160 | 28.352 | 1.00 | 15.11 | E | C |
| ATOM | 5577 | O | PHE | E | 158 | −6.620 | 45.544 | 27.390 | 1.00 | 15.55 | E | O |
| ATOM | 5578 | N | PRO | E | 159 | −6.169 | 47.511 | 28.402 | 1.00 | 15.75 | E | N |
| ATOM | 5579 | CD | PRO | E | 159 | −5.602 | 48.317 | 29.495 | 1.00 | 14.60 | E | C |
| ATOM | 5580 | CA | PRO | E | 159 | −6.703 | 48.370 | 27.333 | 1.00 | 15.13 | E | C |
| ATOM | 5581 | CB | PRO | E | 159 | −6.397 | 49.789 | 27.819 | 1.00 | 14.72 | E | C |
| ATOM | 5582 | CG | PRO | E | 159 | −5.311 | 49.619 | 28.823 | 1.00 | 14.01 | E | C |
| ATOM | 5583 | C | PRO | E | 159 | −6.142 | 48.113 | 25.935 | 1.00 | 16.44 | E | C |
| ATOM | 5584 | O | PRO | E | 159 | −4.975 | 47.759 | 25.773 | 1.00 | 15.86 | E | O |
| ATOM | 5585 | N | LYS | E | 160 | −6.988 | 48.319 | 24.929 | 1.00 | 18.53 | E | N |
| ATOM | 5586 | CA | LYS | E | 160 | −6.617 | 48.102 | 23.537 | 1.00 | 18.36 | E | C |
| ATOM | 5587 | CB | LYS | E | 160 | −7.865 | 48.128 | 22.648 | 1.00 | 19.44 | E | C |
| ATOM | 5588 | CG | LYS | E | 160 | −8.713 | 46.873 | 22.743 | 1.00 | 24.74 | E | C |
| ATOM | 5589 | CD | LYS | E | 160 | −10.078 | 47.045 | 22.074 | 1.00 | 32.35 | E | C |
| ATOM | 5590 | CE | LYS | E | 160 | −10.841 | 48.270 | 22.602 | 1.00 | 34.95 | E | C |
| ATOM | 5591 | NZ | LYS | E | 160 | −11.171 | 48.181 | 24.057 | 1.00 | 36.21 | E | N |
| ATOM | 5592 | C | LYS | E | 160 | −5.594 | 49.078 | 22.979 | 1.00 | 16.84 | E | C |
| ATOM | 5593 | O | LYS | E | 160 | −4.611 | 48.661 | 22.374 | 1.00 | 17.58 | E | O |
| ATOM | 5594 | N | THR | E | 161 | −5.803 | 50.374 | 23.188 | 1.00 | 17.08 | E | N |
| ATOM | 5595 | CA | THR | E | 161 | −4.882 | 51.349 | 22.624 | 1.00 | 19.02 | E | C |
| ATOM | 5596 | CB | THR | E | 161 | −5.361 | 52.806 | 22.880 | 1.00 | 18.38 | E | C |
| ATOM | 5597 | OG1 | THR | E | 161 | −4.683 | 53.361 | 24.004 | 1.00 | 25.32 | E | O |
| ATOM | 5598 | CG2 | THR | E | 161 | −6.856 | 52.838 | 23.110 | 1.00 | 16.72 | E | C |
| ATOM | 5599 | C | THR | E | 161 | −3.410 | 51.171 | 22.998 | 1.00 | 19.23 | E | C |
| ATOM | 5600 | O | THR | E | 161 | −2.545 | 51.276 | 22.129 | 1.00 | 22.85 | E | O |
| ATOM | 5601 | N | PRO | E | 162 | −3.092 | 50.911 | 24.279 | 1.00 | 19.99 | E | N |
| ATOM | 5602 | CD | PRO | E | 162 | −3.936 | 50.818 | 25.479 | 1.00 | 20.56 | E | C |
| ATOM | 5603 | CA | PRO | E | 162 | −1.670 | 50.731 | 24.607 | 1.00 | 18.78 | E | C |
| ATOM | 5604 | CB | PRO | E | 162 | −1.663 | 50.526 | 26.120 | 1.00 | 15.28 | E | C |
| ATOM | 5605 | CG | PRO | E | 162 | −2.954 | 51.051 | 26.586 | 1.00 | 16.06 | E | C |
| ATOM | 5606 | C | PRO | E | 162 | −1.081 | 49.523 | 23.871 | 1.00 | 17.58 | E | C |
| ATOM | 5607 | O | PRO | E | 162 | 0.113 | 49.473 | 23.595 | 1.00 | 17.08 | E | O |
| ATOM | 5608 | N | SER | E | 163 | −1.931 | 48.549 | 23.563 | 1.00 | 17.40 | E | N |
| ATOM | 5609 | CA | SER | E | 163 | −1.507 | 47.346 | 22.851 | 1.00 | 19.00 | E | C |
| ATOM | 5610 | CB | SER | E | 163 | −2.593 | 46.277 | 22.938 | 1.00 | 19.74 | E | C |
| ATOM | 5611 | OG | SER | E | 163 | −2.540 | 45.612 | 24.188 | 1.00 | 21.97 | E | O |
| ATOM | 5612 | C | SER | E | 163 | −1.219 | 47.664 | 21.382 | 1.00 | 20.40 | E | C |
| ATOM | 5613 | O | SER | E | 163 | −0.218 | 47.220 | 20.822 | 1.00 | 21.01 | E | O |
| ATOM | 5614 | N | LYS | E | 164 | −2.103 | 48.435 | 20.761 | 1.00 | 20.57 | E | N |
| ATOM | 5615 | CA | LYS | E | 164 | −1.913 | 48.819 | 19.375 | 1.00 | 20.33 | E | C |
| ATOM | 5616 | CB | LYS | E | 164 | −2.991 | 49.813 | 18.951 | 1.00 | 17.02 | E | C |
| ATOM | 5617 | CG | LYS | E | 164 | −4.344 | 49.175 | 18.709 | 1.00 | 17.96 | E | C |
| ATOM | 5618 | CD | LYS | E | 164 | −5.399 | 50.234 | 18.455 | 1.00 | 23.19 | E | C |
| ATOM | 5619 | CE | LYS | E | 164 | −6.776 | 49.614 | 18.287 | 1.00 | 28.34 | E | C |
| ATOM | 5620 | NZ | LYS | E | 164 | −7.842 | 50.662 | 18.280 | 1.00 | 34.33 | E | N |
| ATOM | 5621 | C | LYS | E | 164 | −0.530 | 49.441 | 19.181 | 1.00 | 21.98 | E | C |
| ATOM | 5622 | O | LYS | E | 164 | 0.153 | 49.148 | 18.194 | 1.00 | 23.52 | E | O |
| ATOM | 5623 | N | TYR | E | 165 | −0.114 | 50.291 | 20.118 | 1.00 | 19.93 | E | N |
| ATOM | 5624 | CA | TYR | E | 165 | 1.193 | 50.936 | 20.018 | 1.00 | 21.76 | E | C |
| ATOM | 5625 | CB | TYR | E | 165 | 1.332 | 52.045 | 21.060 | 1.00 | 19.75 | E | C |
| ATOM | 5626 | CG | TYR | E | 165 | 0.832 | 53.378 | 20.580 | 1.00 | 18.11 | E | C |
| ATOM | 5627 | CD1 | TYR | E | 165 | 1.656 | 54.229 | 19.849 | 1.00 | 14.99 | E | C |
| ATOM | 5628 | CE1 | TYR | E | 165 | 1.181 | 55.440 | 19.356 | 1.00 | 15.68 | E | C |
| ATOM | 5629 | CD2 | TYR | E | 165 | −0.485 | 53.772 | 20.816 | 1.00 | 19.18 | E | C |
| ATOM | 5630 | CE2 | TYR | E | 165 | −0.973 | 54.985 | 20.327 | 1.00 | 18.20 | E | C |
| ATOM | 5631 | CZ | TYR | E | 165 | −0.132 | 55.810 | 19.595 | 1.00 | 17.87 | E | C |
| ATOM | 5632 | OH | TYR | E | 165 | −0.610 | 56.992 | 19.079 | 1.00 | 25.12 | E | O |
| ATOM | 5633 | C | TYR | E | 165 | 2.310 | 49.924 | 20.214 | 1.00 | 24.90 | E | C |
| ATOM | 5634 | O | TYR | E | 165 | 3.372 | 50.028 | 19.594 | 1.00 | 26.86 | E | O |
| ATOM | 5635 | N | LEU | E | 166 | 2.070 | 48.945 | 21.083 | 1.00 | 24.76 | E | N |
| ATOM | 5636 | CA | LEU | E | 166 | 3.061 | 47.917 | 21.353 | 1.00 | 22.57 | E | C |
| ATOM | 5637 | CB | LEU | E | 166 | 2.584 | 47.014 | 22.496 | 1.00 | 22.79 | E | C |
| ATOM | 5638 | CG | LEU | E | 166 | 2.635 | 47.581 | 23.926 | 1.00 | 22.22 | E | C |
| ATOM | 5639 | CD1 | LEU | E | 166 | 2.152 | 46.526 | 24.907 | 1.00 | 19.69 | E | C |
| ATOM | 5640 | CD2 | LEU | E | 166 | 4.051 | 48.014 | 24.278 | 1.00 | 16.63 | E | C |
| ATOM | 5641 | C | LEU | E | 166 | 3.295 | 47.091 | 20.093 | 1.00 | 22.66 | E | C |
| ATOM | 5642 | O | LEU | E | 166 | 4.435 | 46.865 | 19.696 | 1.00 | 22.60 | E | O |
| ATOM | 5643 | N | ARG | E | 167 | 2.210 | 46.647 | 19.465 | 1.00 | 24.02 | E | N |
| ATOM | 5644 | CA | ARG | E | 167 | 2.312 | 45.848 | 18.245 | 1.00 | 24.12 | E | C |
| ATOM | 5645 | CB | ARG | E | 167 | 0.915 | 45.457 | 17.746 | 1.00 | 21.22 | E | C |
| ATOM | 5646 | CG | ARG | E | 167 | 0.194 | 44.421 | 18.618 | 1.00 | 21.66 | E | C |
| ATOM | 5647 | CD | ARG | E | 167 | 1.052 | 43.182 | 18.908 | 1.00 | 20.15 | E | C |
| ATOM | 5648 | NE | ARG | E | 167 | 1.929 | 43.358 | 20.072 | 1.00 | 22.59 | E | N |
| ATOM | 5649 | CZ | ARG | E | 167 | 1.518 | 43.385 | 21.344 | 1.00 | 19.45 | E | C |
| ATOM | 5650 | NH1 | ARG | E | 167 | 0.234 | 43.245 | 21.641 | 1.00 | 17.09 | E | N |
| ATOM | 5651 | NH2 | ARG | E | 167 | 2.393 | 43.560 | 22.328 | 1.00 | 14.79 | E | N |
| ATOM | 5652 | C | ARG | E | 167 | 3.066 | 46.640 | 17.171 | 1.00 | 25.76 | E | C |
| ATOM | 5653 | O | ARG | E | 167 | 3.958 | 46.103 | 16.506 | 1.00 | 23.66 | E | O |
| ATOM | 5654 | N | SER | E | 168 | 2.717 | 47.919 | 17.021 | 1.00 | 25.53 | E | N |
| ATOM | 5655 | CA | SER | E | 168 | 3.368 | 48.795 | 16.045 | 1.00 | 26.06 | E | C |
| ATOM | 5656 | CB | SER | E | 168 | 2.873 | 50.230 | 16.184 | 1.00 | 26.46 | E | C |
| ATOM | 5657 | OG | SER | E | 168 | 1.463 | 50.295 | 16.101 | 1.00 | 35.95 | E | O |
| ATOM | 5658 | C | SER | E | 168 | 4.860 | 48.805 | 16.270 | 1.00 | 27.09 | E | C |
| ATOM | 5659 | O | SER | E | 168 | 5.641 | 48.542 | 15.357 | 1.00 | 30.14 | E | O |
| ATOM | 5660 | N | ILE | E | 169 | 5.247 | 49.134 | 17.496 | 1.00 | 26.94 | E | N |
| ATOM | 5661 | CA | ILE | E | 169 | 6.647 | 49.198 | 17.873 | 1.00 | 26.41 | E | C |
| ATOM | 5662 | CB | ILE | E | 169 | 6.792 | 49.465 | 19.392 | 1.00 | 25.84 | E | C |
| ATOM | 5663 | CG2 | ILE | E | 169 | 8.223 | 49.203 | 19.840 | 1.00 | 25.80 | E | C |
| ATOM | 5664 | CG1 | ILE | E | 169 | 6.383 | 50.915 | 19.696 | 1.00 | 25.16 | E | C |
| ATOM | 5665 | CD1 | ILE | E | 169 | 6.668 | 51.372 | 21.104 | 1.00 | 20.49 | E | C |
| ATOM | 5666 | C | ILE | E | 169 | 7.355 | 47.904 | 17.507 | 1.00 | 29.30 | E | C |
| ATOM | 5667 | O | ILE | E | 169 | 8.515 | 47.919 | 17.099 | 1.00 | 27.67 | E | O |
| ATOM | 5668 | N | GLU | E | 170 | 6.646 | 46.788 | 17.639 | 1.00 | 31.28 | E | N |
| ATOM | 5669 | CA | GLU | E | 170 | 7.213 | 45.482 | 17.333 | 1.00 | 33.37 | E | C |
| ATOM | 5670 | CB | GLU | E | 170 | 6.380 | 44.383 | 17.986 | 1.00 | 33.92 | E | C |
| ATOM | 5671 | CG | GLU | E | 170 | 6.628 | 44.221 | 19.465 | 1.00 | 36.96 | E | C |
| ATOM | 5672 | CD | GLU | E | 170 | 5.434 | 43.626 | 20.187 | 1.00 | 40.21 | E | C |
| ATOM | 5673 | OE1 | GLU | E | 170 | 5.292 | 43.879 | 21.406 | 1.00 | 40.38 | E | O |
| ATOM | 5674 | OE2 | GLU | E | 170 | 4.641 | 42.908 | 19.533 | 1.00 | 38.31 | E | O |
| ATOM | 5675 | C | GLU | E | 170 | 7.296 | 45.216 | 15.837 | 1.00 | 36.57 | E | C |
| ATOM | 5676 | O | GLU | E | 170 | 8.087 | 44.383 | 15.392 | 1.00 | 37.34 | E | O |
| ATOM | 5677 | N | GLY | E | 171 | 6.476 | 45.916 | 15.061 | 1.00 | 37.10 | E | N |
| ATOM | 5678 | CA | GLY | E | 171 | 6.486 | 45.708 | 13.628 | 1.00 | 40.93 | E | C |
| ATOM | 5679 | C | GLY | E | 171 | 5.439 | 44.702 | 13.182 | 1.00 | 42.27 | E | C |
| ATOM | 5680 | O | GLY | E | 171 | 5.546 | 44.123 | 12.100 | 1.00 | 43.24 | E | O |
| ATOM | 5681 | N | THR | E | 172 | 4.428 | 44.485 | 14.016 | 1.00 | 43.83 | E | N |
| ATOM | 5682 | CA | THR | E | 172 | 3.361 | 43.555 | 13.678 | 1.00 | 45.47 | E | C |
| ATOM | 5683 | CB | THR | E | 172 | 3.230 | 42.423 | 14.731 | 1.00 | 44.82 | E | C |
| ATOM | 5684 | OG1 | THR | E | 172 | 2.014 | 42.590 | 15.470 | 1.00 | 44.95 | E | O |
| ATOM | 5685 | CG2 | THR | E | 172 | 4.415 | 42.433 | 15.688 | 1.00 | 43.06 | E | C |
| ATOM | 5686 | C | THR | E | 172 | 2.033 | 44.303 | 13.565 | 1.00 | 46.51 | E | C |
| ATOM | 5687 | O | THR | E | 172 | 1.877 | 45.402 | 14.098 | 1.00 | 45.11 | E | O |
| ATOM | 5688 | N | ALA | E | 173 | 1.086 | 43.710 | 12.846 | 1.00 | 50.37 | E | N |
| ATOM | 5689 | CA | ALA | E | 173 | −0.229 | 44.314 | 12.662 | 1.00 | 52.27 | E | C |
| ATOM | 5690 | CB | ALA | E | 173 | −0.872 | 43.790 | 11.385 | 1.00 | 51.81 | E | C |
| ATOM | 5691 | C | ALA | E | 173 | −1.091 | 43.970 | 13.870 | 1.00 | 52.96 | E | C |
| ATOM | 5692 | O | ALA | E | 173 | −0.937 | 42.902 | 14.465 | 1.00 | 55.17 | E | O |
| ATOM | 5693 | N | TRP | E | 174 | −1.999 | 44.869 | 14.233 | 1.00 | 51.76 | E | N |
| ATOM | 5694 | CA | TRP | E | 174 | −2.848 | 44.640 | 15.393 | 1.00 | 50.76 | E | C |
| ATOM | 5695 | CB | TRP | E | 174 | −3.358 | 45.973 | 15.947 | 1.00 | 49.51 | E | C |
| ATOM | 5696 | CG | TRP | E | 174 | −4.149 | 45.809 | 17.209 | 1.00 | 47.20 | E | C |
| ATOM | 5697 | CD2 | TRP | E | 174 | −5.557 | 46.002 | 17.363 | 1.00 | 46.84 | E | C |
| ATOM | 5698 | CE2 | TRP | E | 174 | −5.878 | 45.690 | 18.702 | 1.00 | 45.65 | E | C |
| ATOM | 5699 | CE3 | TRP | E | 174 | −6.580 | 46.409 | 16.495 | 1.00 | 49.31 | E | C |
| ATOM | 5700 | CD1 | TRP | E | 174 | −3.683 | 45.400 | 18.429 | 1.00 | 44.78 | E | C |
| ATOM | 5701 | NE1 | TRP | E | 174 | −4.717 | 45.324 | 19.331 | 1.00 | 42.46 | E | N |
| ATOM | 5702 | CZ2 | TRP | E | 174 | −7.183 | 45.772 | 19.196 | 1.00 | 48.00 | E | C |
| ATOM | 5703 | CZ3 | TRP | E | 174 | −7.880 | 46.494 | 16.987 | 1.00 | 51.30 | E | C |
| ATOM | 5704 | CH2 | TRP | E | 174 | −8.169 | 46.172 | 18.327 | 1.00 | 50.50 | E | C |
| ATOM | 5705 | C | TRP | E | 174 | −4.025 | 43.704 | 15.149 | 1.00 | 51.55 | E | C |
| ATOM | 5706 | O | TRP | E | 174 | −4.807 | 43.890 | 14.218 | 1.00 | 52.84 | E | O |
| ATOM | 5707 | N | LYS | E | 175 | −4.144 | 42.705 | 16.017 | 1.00 | 52.66 | E | N |
| ATOM | 5708 | CA | LYS | E | 175 | −5.212 | 41.714 | 15.944 | 1.00 | 54.45 | E | C |
| ATOM | 5709 | CB | LYS | E | 175 | −4.754 | 40.415 | 16.609 | 1.00 | 56.71 | E | C |
| ATOM | 5710 | CG | LYS | E | 175 | −3.778 | 40.619 | 17.775 | 1.00 | 58.19 | E | C |
| ATOM | 5711 | CD | LYS | E | 175 | −3.090 | 39.309 | 18.172 | 1.00 | 59.54 | E | C |
| ATOM | 5712 | CE | LYS | E | 175 | −2.486 | 38.588 | 16.961 | 1.00 | 60.94 | E | C |
| ATOM | 5713 | NZ | LYS | E | 175 | −3.393 | 37.526 | 16.404 | 1.00 | 60.71 | E | N |
| ATOM | 5714 | C | LYS | E | 175 | −6.492 | 42.204 | 16.624 | 1.00 | 54.96 | E | C |
| ATOM | 5715 | O | LYS | E | 175 | −7.023 | 43.261 | 16.282 | 1.00 | 55.79 | E | O |
| ATOM | 5716 | N | ALA | E | 176 | −6.977 | 41.418 | 17.585 | 1.00 | 54.87 | E | N |
| ATOM | 5717 | CA | ALA | E | 176 | −8.190 | 41.731 | 18.339 | 1.00 | 54.90 | E | C |
| ATOM | 5718 | CB | ALA | E | 176 | −9.328 | 42.104 | 17.388 | 1.00 | 50.91 | E | C |
| ATOM | 5719 | C | ALA | E | 176 | −8.593 | 40.522 | 19.188 | 1.00 | 55.51 | E | C |
| ATOM | 5720 | O | ALA | E | 176 | −9.656 | 40.521 | 19.814 | 1.00 | 57.49 | E | O |
| ATOM | 5721 | N | ASN | E | 177 | −7.732 | 39.504 | 19.203 | 1.00 | 56.33 | E | N |
| ATOM | 5722 | CA | ASN | E | 177 | −7.962 | 38.265 | 19.955 | 1.00 | 56.79 | E | C |
| ATOM | 5723 | CB | ASN | E | 177 | −6.619 | 37.598 | 20.292 | 1.00 | 59.04 | E | C |
| ATOM | 5724 | CG | ASN | E | 177 | −5.830 | 38.360 | 21.356 | 1.00 | 62.81 | E | C |
| ATOM | 5725 | OD1 | ASN | E | 177 | −5.793 | 39.595 | 21.357 | 1.00 | 63.38 | E | O |
| ATOM | 5726 | ND2 | ASN | E | 177 | −5.195 | 37.622 | 22.267 | 1.00 | 62.24 | E | N |
| ATOM | 5727 | C | ASN | E | 177 | −8.781 | 38.434 | 21.238 | 1.00 | 54.70 | E | C |
| ATOM | 5728 | O | ASN | E | 177 | −8.341 | 39.081 | 22.193 | 1.00 | 53.68 | E | O |
| ATOM | 5729 | N | GLU | E | 178 | −9.974 | 37.845 | 21.250 | 1.00 | 54.13 | E | N |
| ATOM | 5730 | CA | GLU | E | 178 | −10.854 | 37.918 | 22.412 | 1.00 | 53.73 | E | C |
| ATOM | 5731 | CB | GLU | E | 178 | −12.282 | 38.271 | 21.977 | 1.00 | 54.88 | E | C |
| ATOM | 5732 | CG | GLU | E | 178 | −12.461 | 39.717 | 21.526 | 1.00 | 57.35 | E | C |
| ATOM | 5733 | CD | GLU | E | 178 | −12.219 | 40.729 | 22.645 | 1.00 | 60.36 | E | C |
| ATOM | 5734 | OE1 | GLU | E | 178 | −11.272 | 40.542 | 23.440 | 1.00 | 59.60 | E | O |
| ATOM | 5735 | OE2 | GLU | E | 178 | −12.980 | 41.719 | 22.724 | 1.00 | 62.58 | E | O |
| ATOM | 5736 | C | GLU | E | 178 | −10.854 | 36.591 | 23.175 | 1.00 | 52.06 | E | C |
| ATOM | 5737 | O | GLU | E | 178 | −11.799 | 36.278 | 23.902 | 1.00 | 52.63 | E | O |
| ATOM | 5738 | N | SER | E | 179 | −9.783 | 35.819 | 23.011 | 1.00 | 50.72 | E | N |
| ATOM | 5739 | CA | SER | E | 179 | −9.657 | 34.525 | 23.675 | 1.00 | 46.28 | E | C |
| ATOM | 5740 | CB | SER | E | 179 | −8.682 | 33.633 | 22.904 | 1.00 | 43.95 | E | C |
| ATOM | 5741 | OG | SER | E | 179 | −7.655 | 34.406 | 22.306 | 1.00 | 44.91 | E | O |
| ATOM | 5742 | C | SER | E | 179 | −9.192 | 34.655 | 25.124 | 1.00 | 44.92 | E | C |
| ATOM | 5743 | O | SER | E | 179 | −9.548 | 33.828 | 25.963 | 1.00 | 44.79 | E | O |
| ATOM | 5744 | N | SER | E | 180 | −8.400 | 35.688 | 25.412 | 1.00 | 42.76 | E | N |
| ATOM | 5745 | CA | SER | E | 180 | −7.891 | 35.916 | 26.765 | 1.00 | 40.60 | E | C |
| ATOM | 5746 | CB | SER | E | 180 | −6.437 | 36.375 | 26.712 | 1.00 | 40.56 | E | C |
| ATOM | 5747 | OG | SER | E | 180 | −5.823 | 35.973 | 25.500 | 1.00 | 43.05 | E | O |
| ATOM | 5748 | C | SER | E | 180 | −8.729 | 36.958 | 27.490 | 1.00 | 39.16 | E | C |
| ATOM | 5749 | O | SER | E | 180 | −8.287 | 37.576 | 28.458 | 1.00 | 38.51 | E | O |
| ATOM | 5750 | N | TYR | E | 181 | −9.946 | 37.145 | 27.002 | 1.00 | 39.89 | E | N |
| ATOM | 5751 | CA | TYR | E | 181 | −10.873 | 38.102 | 27.579 | 1.00 | 41.78 | E | C |
| ATOM | 5752 | CB | TYR | E | 181 | −11.948 | 38.452 | 26.544 | 1.00 | 45.87 | E | C |
| ATOM | 5753 | CG | TYR | E | 181 | −12.214 | 39.929 | 26.364 | 1.00 | 50.93 | E | C |
| ATOM | 5754 | CD1 | TYR | E | 181 | −13.523 | 40.422 | 26.344 | 1.00 | 53.79 | E | C |
| ATOM | 5755 | CE1 | TYR | E | 181 | −13.784 | 41.783 | 26.146 | 1.00 | 56.40 | E | C |
| ATOM | 5756 | CD2 | TYR | E | 181 | −11.164 | 40.834 | 26.185 | 1.00 | 52.85 | E | C |
| ATOM | 5757 | CE2 | TYR | E | 181 | −11.410 | 42.199 | 25.985 | 1.00 | 56.53 | E | C |
| ATOM | 5758 | CZ | TYR | E | 181 | −12.723 | 42.667 | 25.965 | 1.00 | 57.86 | E | C |
| ATOM | 5759 | OH | TYR | E | 181 | −12.974 | 44.012 | 25.759 | 1.00 | 58.17 | E | O |
| ATOM | 5760 | C | TYR | E | 181 | −11.530 | 37.482 | 28.814 | 1.00 | 40.38 | E | C |
| ATOM | 5761 | O | TYR | E | 181 | −11.914 | 36.307 | 28.804 | 1.00 | 41.37 | E | O |
| ATOM | 5762 | N | PRO | E | 182 | −11.649 | 38.254 | 29.905 | 1.00 | 38.86 | E | N |
| ATOM | 5763 | CD | PRO | E | 182 | −11.203 | 39.640 | 30.117 | 1.00 | 34.95 | E | C |
| ATOM | 5764 | CA | PRO | E | 182 | −12.283 | 37.687 | 31.099 | 1.00 | 37.57 | E | C |
| ATOM | 5765 | CB | PRO | E | 182 | −12.294 | 38.852 | 32.093 | 1.00 | 35.44 | E | C |
| ATOM | 5766 | CG | PRO | E | 182 | −12.023 | 40.073 | 31.281 | 1.00 | 31.82 | E | C |
| ATOM | 5767 | C | PRO | E | 182 | −13.697 | 37.195 | 30.776 | 1.00 | 38.42 | E | C |
| ATOM | 5768 | O | PRO | E | 182 | −14.285 | 37.609 | 29.768 | 1.00 | 39.59 | E | O |
| ATOM | 5769 | N | VAL | E | 183 | −14.227 | 36.302 | 31.615 | 1.00 | 36.64 | E | N |
| ATOM | 5770 | CA | VAL | E | 183 | −15.576 | 35.768 | 31.431 | 1.00 | 32.96 | E | C |
| ATOM | 5771 | CB | VAL | E | 183 | −15.567 | 34.233 | 31.271 | 1.00 | 30.94 | E | C |
| ATOM | 5772 | CG1 | VAL | E | 183 | −16.944 | 33.742 | 30.869 | 1.00 | 25.48 | E | C |
| ATOM | 5773 | CG2 | VAL | E | 183 | −14.542 | 33.825 | 30.231 | 1.00 | 31.41 | E | C |
| ATOM | 5774 | C | VAL | E | 183 | −16.443 | 36.128 | 32.639 | 1.00 | 33.88 | E | C |
| ATOM | 5775 | O | VAL | E | 183 | −16.351 | 35.499 | 33.696 | 1.00 | 33.04 | E | O |
| ATOM | 5776 | N | PHE | E | 184 | −17.270 | 37.155 | 32.480 | 1.00 | 33.17 | E | N |
| ATOM | 5777 | CA | PHE | E | 184 | −18.162 | 37.603 | 33.543 | 1.00 | 35.36 | E | C |
| ATOM | 5778 | CB | PHE | E | 184 | −18.486 | 39.088 | 33.370 | 1.00 | 39.96 | E | C |
| ATOM | 5779 | CG | PHE | E | 184 | −17.336 | 39.998 | 33.675 | 1.00 | 46.10 | E | C |
| ATOM | 5780 | CD1 | PHE | E | 184 | −17.404 | 40.882 | 34.747 | 1.00 | 49.54 | E | C |
| ATOM | 5781 | CD2 | PHE | E | 184 | −16.185 | 39.982 | 32.886 | 1.00 | 47.19 | E | C |
| ATOM | 5782 | CE1 | PHE | E | 184 | −16.338 | 41.745 | 35.032 | 1.00 | 52.12 | E | C |
| ATOM | 5783 | CE2 | PHE | E | 184 | −15.115 | 40.836 | 33.160 | 1.00 | 47.31 | E | C |
| ATOM | 5784 | CZ | PHE | E | 184 | −15.192 | 41.721 | 34.236 | 1.00 | 49.78 | E | C |
| ATOM | 5785 | C | PHE | E | 184 | −19.452 | 36.807 | 33.448 | 1.00 | 34.59 | E | C |
| ATOM | 5786 | O | PHE | E | 184 | −20.004 | 36.655 | 32.360 | 1.00 | 35.44 | E | O |
| ATOM | 5787 | N | THR | E | 185 | −19.947 | 36.294 | 34.567 | 1.00 | 33.14 | E | N |
| ATOM | 5788 | CA | THR | E | 185 | −21.186 | 35.530 | 34.499 | 1.00 | 33.68 | E | C |
| ATOM | 5789 | CB | THR | E | 185 | −21.557 | 34.902 | 35.876 | 1.00 | 30.50 | E | C |
| ATOM | 5790 | OG1 | THR | E | 185 | −22.904 | 35.246 | 36.228 | 1.00 | 30.07 | E | O |
| ATOM | 5791 | CG2 | THR | E | 185 | −20.600 | 35.366 | 36.943 | 1.00 | 29.94 | E | C |
| ATOM | 5792 | C | THR | E | 185 | −22.291 | 36.461 | 33.983 | 1.00 | 34.04 | E | C |
| ATOM | 5793 | O | THR | E | 185 | −22.397 | 37.616 | 34.406 | 1.00 | 33.98 | E | O |
| ATOM | 5794 | N | PRO | E | 186 | −23.109 | 35.969 | 33.035 | 1.00 | 33.66 | E | N |
| ATOM | 5795 | CD | PRO | E | 186 | −23.031 | 34.608 | 32.472 | 1.00 | 32.04 | E | C |
| ATOM | 5796 | CA | PRO | E | 186 | −24.205 | 36.737 | 32.434 | 1.00 | 34.25 | E | C |
| ATOM | 5797 | CB | PRO | E | 186 | −24.816 | 35.767 | 31.419 | 1.00 | 34.09 | E | C |
| ATOM | 5798 | CG | PRO | E | 186 | −24.395 | 34.412 | 31.890 | 1.00 | 33.59 | E | C |
| ATOM | 5799 | C | PRO | E | 186 | −25.252 | 37.267 | 33.395 | 1.00 | 34.69 | E | C |
| ATOM | 5800 | O | PRO | E | 186 | −25.440 | 36.733 | 34.486 | 1.00 | 38.33 | E | O |
| ATOM | 5801 | N | ALA | E | 187 | −25.928 | 38.332 | 32.978 | 1.00 | 33.22 | E | N |
| ATOM | 5802 | CA | ALA | E | 187 | −26.986 | 38.922 | 33.780 | 1.00 | 35.92 | E | C |
| ATOM | 5803 | CB | ALA | E | 187 | −27.417 | 40.263 | 33.181 | 1.00 | 30.92 | E | C |
| ATOM | 5804 | C | ALA | E | 187 | −28.158 | 37.944 | 33.772 | 1.00 | 36.74 | E | C |
| ATOM | 5805 | O | ALA | E | 187 | −28.464 | 37.344 | 32.742 | 1.00 | 36.96 | E | O |
| ATOM | 5806 | N | LEU | E | 188 | −28.804 | 37.759 | 34.917 | 1.00 | 38.73 | E | N |
| ATOM | 5807 | CA | LEU | E | 188 | −29.937 | 36.855 | 34.952 | 1.00 | 41.72 | E | C |
| ATOM | 5808 | CB | LEU | E | 188 | −30.223 | 36.380 | 36.382 | 1.00 | 40.99 | E | C |
| ATOM | 5809 | CG | LEU | E | 188 | −29.917 | 37.301 | 37.560 | 1.00 | 42.45 | E | C |
| ATOM | 5810 | CD1 | LEU | E | 188 | −31.217 | 37.661 | 38.276 | 1.00 | 43.74 | E | C |
| ATOM | 5811 | CD2 | LEU | E | 188 | −28.956 | 36.601 | 38.517 | 1.00 | 40.45 | E | C |
| ATOM | 5812 | C | LEU | E | 188 | −31.128 | 37.615 | 34.393 | 1.00 | 42.06 | E | C |
| ATOM | 5813 | O | LEU | E | 188 | −31.225 | 38.828 | 34.566 | 1.00 | 42.07 | E | O |
| ATOM | 5814 | N | LYS | E | 189 | −32.020 | 36.902 | 33.711 | 1.00 | 42.95 | E | N |
| ATOM | 5815 | CA | LYS | E | 189 | −33.203 | 37.507 | 33.117 | 1.00 | 44.69 | E | C |
| ATOM | 5816 | CB | LYS | E | 189 | −33.990 | 36.456 | 32.334 | 1.00 | 41.90 | E | C |
| ATOM | 5817 | CG | LYS | E | 189 | −33.123 | 35.558 | 31.476 | 1.00 | 42.37 | E | C |
| ATOM | 5818 | CD | LYS | E | 189 | −33.010 | 36.093 | 30.059 | 1.00 | 45.74 | E | C |
| ATOM | 5819 | CE | LYS | E | 189 | −31.573 | 36.465 | 29.707 | 1.00 | 48.32 | E | C |
| ATOM | 5820 | NZ | LYS | E | 189 | −30.703 | 35.263 | 29.531 | 1.00 | 49.40 | E | N |
| ATOM | 5821 | C | LYS | E | 189 | −34.094 | 38.130 | 34.182 | 1.00 | 47.72 | E | C |
| ATOM | 5822 | O | LYS | E | 189 | −33.951 | 37.846 | 35.370 | 1.00 | 47.23 | E | O |
| ATOM | 5823 | N | LYS | E | 190 | −35.005 | 38.996 | 33.753 | 1.00 | 51.41 | E | N |
| ATOM | 5824 | CA | LYS | E | 190 | −35.926 | 39.640 | 34.683 | 1.00 | 54.71 | E | C |
| ATOM | 5825 | CB | LYS | E | 190 | −36.966 | 40.464 | 33.915 | 1.00 | 57.94 | E | C |
| ATOM | 5826 | CG | LYS | E | 190 | −37.728 | 41.482 | 34.761 | 1.00 | 60.20 | E | C |
| ATOM | 5827 | CD | LYS | E | 190 | −39.227 | 41.482 | 34.444 | 1.00 | 63.51 | E | C |
| ATOM | 5828 | CE | LYS | E | 190 | −39.504 | 41.642 | 32.942 | 1.00 | 66.91 | E | C |
| ATOM | 5829 | NZ | LYS | E | 190 | −40.424 | 40.586 | 32.404 | 1.00 | 65.82 | E | N |
| ATOM | 5830 | C | LYS | E | 190 | −36.618 | 38.533 | 35.466 | 1.00 | 55.43 | E | C |
| ATOM | 5831 | O | LYS | E | 190 | −37.176 | 37.606 | 34.879 | 1.00 | 58.00 | E | O |
| ATOM | 5832 | N | GLY | E | 191 | −36.570 | 38.616 | 36.789 | 1.00 | 55.40 | E | N |
| ATOM | 5833 | CA | GLY | E | 191 | −37.201 | 37.590 | 37.599 | 1.00 | 55.83 | E | C |
| ATOM | 5834 | C | GLY | E | 191 | −36.748 | 36.188 | 37.219 | 1.00 | 56.00 | E | C |
| ATOM | 5835 | O | GLY | E | 191 | −37.402 | 35.488 | 36.428 | 1.00 | 57.10 | E | O |
| ATOM | 5836 | N | GLU | E | 192 | −35.613 | 35.784 | 37.778 | 1.00 | 50.20 | E | N |
| ATOM | 5837 | CA | GLU | E | 192 | −35.052 | 34.467 | 37.526 | 1.00 | 48.42 | E | C |
| ATOM | 5838 | CB | GLU | E | 192 | −34.002 | 34.523 | 36.408 | 1.00 | 47.53 | E | C |
| ATOM | 5839 | CG | GLU | E | 192 | −33.425 | 33.163 | 36.019 | 1.00 | 46.42 | E | C |
| ATOM | 5840 | CD | GLU | E | 192 | −32.168 | 33.278 | 35.171 | 1.00 | 46.63 | E | C |
| ATOM | 5841 | OE1 | GLU | E | 192 | −31.571 | 32.233 | 34.829 | 1.00 | 45.95 | E | O |
| ATOM | 5842 | OE2 | GLU | E | 192 | −31.775 | 34.414 | 34.841 | 1.00 | 47.42 | E | O |
| ATOM | 5843 | C | GLU | E | 192 | −34.407 | 34.036 | 38.827 | 1.00 | 45.19 | E | C |
| ATOM | 5844 | O | GLU | E | 192 | −34.001 | 34.877 | 39.625 | 1.00 | 44.81 | E | O |
| ATOM | 5845 | N | ASP | E | 193 | −34.329 | 32.731 | 39.053 | 1.00 | 42.78 | E | N |
| ATOM | 5846 | CA | ASP | E | 193 | −33.724 | 32.222 | 40.271 | 1.00 | 36.76 | E | C |
| ATOM | 5847 | CB | ASP | E | 193 | −34.039 | 30.735 | 40.436 | 1.00 | 38.10 | E | C |
| ATOM | 5848 | CG | ASP | E | 193 | −33.761 | 30.234 | 41.836 | 1.00 | 39.58 | E | C |
| ATOM | 5849 | OD1 | ASP | E | 193 | −33.220 | 29.118 | 41.966 | 1.00 | 44.48 | E | O |
| ATOM | 5850 | OD2 | ASP | E | 193 | −34.080 | 30.949 | 42.807 | 1.00 | 41.05 | E | O |
| ATOM | 5851 | C | ASP | E | 193 | −32.216 | 32.443 | 40.212 | 1.00 | 32.85 | E | C |
| ATOM | 5852 | O | ASP | E | 193 | −31.522 | 31.892 | 39.357 | 1.00 | 30.42 | E | O |
| ATOM | 5853 | N | PRO | E | 194 | −31.689 | 33.272 | 41.119 | 1.00 | 30.29 | E | N |
| ATOM | 5854 | CD | PRO | E | 194 | −32.385 | 34.015 | 42.179 | 1.00 | 27.82 | E | C |
| ATOM | 5855 | CA | PRO | E | 194 | −30.251 | 33.533 | 41.126 | 1.00 | 29.79 | E | C |
| ATOM | 5856 | CB | PRO | E | 194 | −30.101 | 34.746 | 42.044 | 1.00 | 27.94 | E | C |
| ATOM | 5857 | CG | PRO | E | 194 | −31.493 | 35.181 | 42.394 | 1.00 | 26.40 | E | C |
| ATOM | 5858 | C | PRO | E | 194 | −29.475 | 32.337 | 41.646 | 1.00 | 29.24 | E | C |
| ATOM | 5859 | O | PRO | E | 194 | −28.252 | 32.275 | 41.510 | 1.00 | 31.31 | E | O |
| ATOM | 5860 | N | PHE | E | 195 | −30.189 | 31.379 | 42.224 | 1.00 | 29.59 | E | N |
| ATOM | 5861 | CA | PHE | E | 195 | −29.544 | 30.199 | 42.785 | 1.00 | 29.78 | E | C |
| ATOM | 5862 | CB | PHE | E | 195 | −29.919 | 30.089 | 44.264 | 1.00 | 27.64 | E | C |
| ATOM | 5863 | CG | PHE | E | 195 | −29.712 | 31.368 | 45.025 | 1.00 | 26.46 | E | C |
| ATOM | 5864 | CD1 | PHE | E | 195 | −28.424 | 31.813 | 45.330 | 1.00 | 24.59 | E | C |
| ATOM | 5865 | CD2 | PHE | E | 195 | −30.792 | 32.157 | 45.392 | 1.00 | 24.94 | E | C |
| ATOM | 5866 | CE1 | PHE | E | 195 | −28.223 | 33.026 | 45.985 | 1.00 | 21.35 | E | C |
| ATOM | 5867 | CE2 | PHE | E | 195 | −30.594 | 33.376 | 46.050 | 1.00 | 25.46 | E | C |
| ATOM | 5868 | CZ | PHE | E | 195 | −29.308 | 33.806 | 46.343 | 1.00 | 20.21 | E | C |
| ATOM | 5869 | C | PHE | E | 195 | −29.836 | 28.885 | 42.063 | 1.00 | 31.39 | E | C |
| ATOM | 5870 | O | PHE | E | 195 | −29.775 | 27.816 | 42.670 | 1.00 | 30.96 | E | O |
| ATOM | 5871 | N | ARG | E | 196 | −30.136 | 28.972 | 40.766 | 1.00 | 33.86 | E | N |
| ATOM | 5872 | CA | ARG | E | 196 | −30.434 | 27.794 | 39.952 | 1.00 | 35.35 | E | C |
| ATOM | 5873 | CB | ARG | E | 196 | −30.683 | 28.199 | 38.497 | 1.00 | 36.52 | E | C |
| ATOM | 5874 | CG | ARG | E | 196 | −31.754 | 29.248 | 38.324 | 1.00 | 39.50 | E | C |
| ATOM | 5875 | CD | ARG | E | 196 | −32.083 | 29.456 | 36.863 | 1.00 | 44.07 | E | C |
| ATOM | 5876 | NE | ARG | E | 196 | −32.181 | 28.189 | 36.150 | 1.00 | 46.61 | E | N |
| ATOM | 5877 | CZ | ARG | E | 196 | −32.724 | 28.052 | 34.947 | 1.00 | 46.92 | E | C |
| ATOM | 5878 | NH1 | ARG | E | 196 | −33.222 | 29.108 | 34.318 | 1.00 | 45.58 | E | N |
| ATOM | 5879 | NH2 | ARG | E | 196 | −32.768 | 26.858 | 34.375 | 1.00 | 47.47 | E | N |
| ATOM | 5880 | C | ARG | E | 196 | −29.295 | 26.784 | 39.999 | 1.00 | 33.93 | E | C |
| ATOM | 5881 | O | ARG | E | 196 | −28.127 | 27.144 | 39.885 | 1.00 | 33.22 | E | O |
| ATOM | 5882 | N | THR | E | 197 | −29.642 | 25.512 | 40.138 | 1.00 | 34.16 | E | N |
| ATOM | 5883 | CA | THR | E | 197 | −28.634 | 24.469 | 40.211 | 1.00 | 35.63 | E | C |
| ATOM | 5884 | CB | THR | E | 197 | −28.682 | 23.789 | 41.593 | 1.00 | 35.95 | E | C |
| ATOM | 5885 | OG1 | THR | E | 197 | −27.480 | 23.044 | 41.801 | 1.00 | 37.47 | E | O |
| ATOM | 5886 | CG2 | THR | E | 197 | −29.887 | 22.861 | 41.698 | 1.00 | 35.91 | E | C |
| ATOM | 5887 | C | THR | E | 197 | −28.788 | 23.407 | 39.121 | 1.00 | 36.62 | E | C |
| ATOM | 5888 | O | THR | E | 197 | −28.138 | 22.363 | 39.170 | 1.00 | 35.31 | E | O |
| ATOM | 5889 | N | ASP | E | 198 | −29.630 | 23.689 | 38.129 | 1.00 | 38.12 | E | N |
| ATOM | 5890 | CA | ASP | E | 198 | −29.896 | 22.746 | 37.044 | 1.00 | 38.37 | E | C |
| ATOM | 5891 | CB | ASP | E | 198 | −31.379 | 22.783 | 36.690 | 1.00 | 37.60 | E | C |
| ATOM | 5892 | CG | ASP | E | 198 | −31.840 | 24.161 | 36.269 | 1.00 | 39.60 | E | C |
| ATOM | 5893 | OD1 | ASP | E | 198 | −31.814 | 25.079 | 37.111 | 1.00 | 41.38 | E | O |
| ATOM | 5894 | OD2 | ASP | E | 198 | −32.230 | 24.333 | 35.095 | 1.00 | 41.40 | E | O |
| ATOM | 5895 | C | ASP | E | 198 | −29.089 | 22.946 | 35.768 | 1.00 | 39.12 | E | C |
| ATOM | 5896 | O | ASP | E | 198 | −29.228 | 22.174 | 34.819 | 1.00 | 39.66 | E | O |
| ATOM | 5897 | N | ASN | E | 199 | −28.249 | 23.971 | 35.735 | 1.00 | 40.31 | E | N |
| ATOM | 5898 | CA | ASN | E | 199 | −27.454 | 24.247 | 34.544 | 1.00 | 39.89 | E | C |
| ATOM | 5899 | CB | ASN | E | 199 | −27.751 | 25.661 | 34.047 | 1.00 | 44.70 | E | C |
| ATOM | 5900 | CG | ASN | E | 199 | −28.042 | 26.630 | 35.188 | 1.00 | 51.64 | E | C |
| ATOM | 5901 | OD1 | ASN | E | 199 | −28.846 | 27.558 | 35.045 | 1.00 | 52.63 | E | O |
| ATOM | 5902 | ND2 | ASN | E | 199 | −27.385 | 26.417 | 36.333 | 1.00 | 52.26 | E | N |
| ATOM | 5903 | C | ASN | E | 199 | −25.960 | 24.096 | 34.800 | 1.00 | 37.35 | E | C |
| ATOM | 5904 | O | ASN | E | 199 | −25.142 | 24.691 | 34.098 | 1.00 | 38.29 | E | O |
| ATOM | 5905 | N | LEU | E | 200 | −25.606 | 23.292 | 35.797 | 1.00 | 34.38 | E | N |
| ATOM | 5906 | CA | LEU | E | 200 | −24.204 | 23.082 | 36.143 | 1.00 | 32.58 | E | C |
| ATOM | 5907 | CB | LEU | E | 200 | −24.066 | 22.706 | 37.623 | 1.00 | 31.49 | E | C |
| ATOM | 5908 | CG | LEU | E | 200 | −24.468 | 23.712 | 38.701 | 1.00 | 31.39 | E | C |
| ATOM | 5909 | CD1 | LEU | E | 200 | −24.595 | 22.993 | 40.021 | 1.00 | 28.86 | E | C |
| ATOM | 5910 | CD2 | LEU | E | 200 | −23.426 | 24.814 | 38.802 | 1.00 | 32.43 | E | C |
| ATOM | 5911 | C | LEU | E | 200 | −23.556 | 21.988 | 35.304 | 1.00 | 30.02 | E | C |
| ATOM | 5912 | O | LEU | E | 200 | −24.199 | 21.001 | 34.953 | 1.00 | 30.50 | E | O |
| ATOM | 5913 | N | PRO | E | 201 | −22.269 | 22.158 | 34.969 | 1.00 | 26.63 | E | N |
| ATOM | 5914 | CD | PRO | E | 201 | −21.440 | 23.327 | 35.297 | 1.00 | 25.56 | E | C |
| ATOM | 5915 | CA | PRO | E | 201 | −21.529 | 21.177 | 34.174 | 1.00 | 27.26 | E | C |
| ATOM | 5916 | CB | PRO | E | 201 | −20.140 | 21.801 | 34.039 | 1.00 | 25.89 | E | C |
| ATOM | 5917 | CG | PRO | E | 201 | −20.348 | 23.248 | 34.291 | 1.00 | 24.35 | E | C |
| ATOM | 5918 | C | PRO | E | 201 | −21.484 | 19.813 | 34.873 | 1.00 | 30.74 | E | C |
| ATOM | 5919 | O | PRO | E | 201 | −21.994 | 19.659 | 35.980 | 1.00 | 32.99 | E | O |
| ATOM | 5920 | N | GLU | E | 202 | −20.875 | 18.829 | 34.224 | 1.00 | 31.84 | E | N |
| ATOM | 5921 | CA | GLU | E | 202 | −20.774 | 17.494 | 34.793 | 1.00 | 36.02 | E | C |
| ATOM | 5922 | CB | GLU | E | 202 | −20.873 | 16.447 | 33.679 | 1.00 | 42.19 | E | C |
| ATOM | 5923 | CG | GLU | E | 202 | −21.922 | 16.774 | 32.609 | 1.00 | 52.14 | E | C |
| ATOM | 5924 | CD | GLU | E | 202 | −21.798 | 15.897 | 31.358 | 1.00 | 58.90 | E | C |
| ATOM | 5925 | OE1 | GLU | E | 202 | −20.680 | 15.391 | 31.085 | 1.00 | 58.69 | E | O |
| ATOM | 5926 | OE2 | GLU | E | 202 | −22.822 | 15.719 | 30.650 | 1.00 | 59.42 | E | O |
| ATOM | 5927 | C | GLU | E | 202 | −19.448 | 17.349 | 35.525 | 1.00 | 34.96 | E | C |
| ATOM | 5928 | O | GLU | E | 202 | −18.515 | 18.108 | 35.279 | 1.00 | 36.66 | E | O |
| ATOM | 5929 | N | ASN | E | 203 | −19.361 | 16.382 | 36.430 | 1.00 | 34.16 | E | N |
| ATOM | 5930 | CA | ASN | E | 203 | −18.123 | 16.168 | 37.174 | 1.00 | 35.42 | E | C |
| ATOM | 5931 | CB | ASN | E | 203 | −18.351 | 15.194 | 38.332 | 1.00 | 33.05 | E | C |
| ATOM | 5932 | CG | ASN | E | 203 | −19.284 | 15.750 | 39.390 | 1.00 | 34.21 | E | C |
| ATOM | 5933 | OD1 | ASN | E | 203 | −19.584 | 15.080 | 40.379 | 1.00 | 35.10 | E | O |
| ATOM | 5934 | ND2 | ASN | E | 203 | −19.752 | 16.978 | 39.187 | 1.00 | 35.86 | E | N |
| ATOM | 5935 | C | ASN | E | 203 | −17.053 | 15.611 | 36.245 | 1.00 | 34.00 | E | C |
| ATOM | 5936 | O | ASN | E | 203 | −17.366 | 14.901 | 35.293 | 1.00 | 33.14 | E | O |
| ATOM | 5937 | N | LEU | E | 204 | −15.794 | 15.928 | 36.529 | 1.00 | 33.65 | E | N |
| ATOM | 5938 | CA | LEU | E | 204 | −14.687 | 15.465 | 35.704 | 1.00 | 34.25 | E | C |
| ATOM | 5939 | CB | LEU | E | 204 | −13.917 | 16.662 | 35.145 | 1.00 | 33.81 | E | C |
| ATOM | 5940 | CG | LEU | E | 204 | −14.682 | 17.481 | 34.103 | 1.00 | 33.83 | E | C |
| ATOM | 5941 | CD1 | LEU | E | 204 | −13.913 | 18.750 | 33.780 | 1.00 | 31.80 | E | C |
| ATOM | 5942 | CD2 | LEU | E | 204 | −14.897 | 16.650 | 32.851 | 1.00 | 31.30 | E | C |
| ATOM | 5943 | C | LEU | E | 204 | −13.737 | 14.541 | 36.456 | 1.00 | 34.33 | E | C |
| ATOM | 5944 | O | LEU | E | 204 | −12.855 | 13.928 | 35.860 | 1.00 | 36.55 | E | O |
| ATOM | 5945 | N | GLY | E | 205 | −13.918 | 14.452 | 37.766 | 1.00 | 33.94 | E | N |
| ATOM | 5946 | CA | GLY | E | 205 | −13.084 | 13.584 | 38.572 | 1.00 | 35.16 | E | C |
| ATOM | 5947 | C | GLY | E | 205 | −11.575 | 13.647 | 38.383 | 1.00 | 36.23 | E | C |
| ATOM | 5948 | O | GLY | E | 205 | −10.898 | 12.627 | 38.545 | 1.00 | 37.15 | E | O |
| ATOM | 5949 | N | TYR | E | 206 | −11.031 | 14.810 | 38.037 | 1.00 | 34.70 | E | N |
| ATOM | 5950 | CA | TYR | E | 206 | −9.581 | 14.916 | 37.886 | 1.00 | 35.01 | E | C |
| ATOM | 5951 | CB | TYR | E | 206 | −9.181 | 16.234 | 37.216 | 1.00 | 36.53 | E | C |
| ATOM | 5952 | CG | TYR | E | 206 | −9.596 | 16.379 | 35.768 | 1.00 | 38.58 | E | C |
| ATOM | 5953 | CD1 | TYR | E | 206 | −9.692 | 15.271 | 34.926 | 1.00 | 39.65 | E | C |
| ATOM | 5954 | CE1 | TYR | E | 206 | −10.058 | 15.413 | 33.588 | 1.00 | 40.58 | E | C |
| ATOM | 5955 | CD2 | TYR | E | 206 | −9.879 | 17.637 | 35.234 | 1.00 | 40.52 | E | C |
| ATOM | 5956 | CE2 | TYR | E | 206 | −10.245 | 17.793 | 33.903 | 1.00 | 41.30 | E | C |
| ATOM | 5957 | CZ | TYR | E | 206 | −10.333 | 16.679 | 33.084 | 1.00 | 42.56 | E | C |
| ATOM | 5958 | OH | TYR | E | 206 | −10.699 | 16.840 | 31.765 | 1.00 | 42.67 | E | O |
| ATOM | 5959 | C | TYR | E | 206 | −9.001 | 14.892 | 39.296 | 1.00 | 34.92 | E | C |
| ATOM | 5960 | O | TYR | E | 206 | −9.733 | 15.037 | 40.278 | 1.00 | 34.37 | E | O |
| ATOM | 5961 | N | HIS | E | 207 | −7.690 | 14.716 | 39.400 | 1.00 | 34.35 | E | N |
| ATOM | 5962 | CA | HIS | E | 207 | −7.047 | 14.684 | 40.705 | 1.00 | 34.88 | E | C |
| ATOM | 5963 | CB | HIS | E | 207 | −6.079 | 13.499 | 40.787 | 1.00 | 36.14 | E | C |
| ATOM | 5964 | CG | HIS | E | 207 | −5.440 | 13.336 | 42.130 | 1.00 | 40.23 | E | C |
| ATOM | 5965 | CD2 | HIS | E | 207 | −5.912 | 12.807 | 43.285 | 1.00 | 39.44 | E | C |
| ATOM | 5966 | ND1 | HIS | E | 207 | −4.160 | 13.775 | 42.404 | 1.00 | 42.60 | E | N |
| ATOM | 5967 | CE1 | HIS | E | 207 | −3.875 | 13.524 | 43.671 | 1.00 | 42.58 | E | C |
| ATOM | 5968 | NE2 | HIS | E | 207 | −4.920 | 12.937 | 44.227 | 1.00 | 40.98 | E | N |
| ATOM | 5969 | C | HIS | E | 207 | −6.296 | 15.993 | 40.945 | 1.00 | 35.20 | E | C |
| ATOM | 5970 | O | HIS | E | 207 | −5.396 | 16.348 | 40.181 | 1.00 | 35.96 | E | O |
| ATOM | 5971 | N | LEU | E | 208 | −6.676 | 16.714 | 41.999 | 1.00 | 34.26 | E | N |
| ATOM | 5972 | CA | LEU | E | 208 | −6.038 | 17.983 | 42.334 | 1.00 | 30.60 | E | C |
| ATOM | 5973 | CB | LEU | E | 208 | −7.074 | 18.957 | 42.876 | 1.00 | 29.65 | E | C |
| ATOM | 5974 | CG | LEU | E | 208 | −8.226 | 19.260 | 41.926 | 1.00 | 28.25 | E | C |
| ATOM | 5975 | CD1 | LEU | E | 208 | −9.317 | 19.967 | 42.696 | 1.00 | 28.11 | E | C |
| ATOM | 5976 | CD2 | LEU | E | 208 | −7.741 | 20.113 | 40.756 | 1.00 | 28.14 | E | C |
| ATOM | 5977 | C | LEU | E | 208 | −4.939 | 17.793 | 43.366 | 1.00 | 31.97 | E | C |
| ATOM | 5978 | O | LEU | E | 208 | −5.067 | 16.986 | 44.282 | 1.00 | 33.11 | E | O |
| ATOM | 5979 | N | LYS | E | 209 | −3.857 | 18.547 | 43.220 | 1.00 | 32.92 | E | N |
| ATOM | 5980 | CA | LYS | E | 209 | −2.743 | 18.441 | 44.148 | 1.00 | 33.86 | E | C |
| ATOM | 5981 | CB | LYS | E | 209 | −1.868 | 17.245 | 43.766 | 1.00 | 35.33 | E | C |
| ATOM | 5982 | CG | LYS | E | 209 | −0.772 | 16.917 | 44.769 | 1.00 | 34.72 | E | C |
| ATOM | 5983 | CD | LYS | E | 209 | 0.184 | 15.865 | 44.211 | 1.00 | 39.37 | E | C |
| ATOM | 5984 | CE | LYS | E | 209 | 1.202 | 15.419 | 45.263 | 1.00 | 40.16 | E | C |
| ATOM | 5985 | NZ | LYS | E | 209 | 2.422 | 14.818 | 44.647 | 1.00 | 39.49 | E | N |
| ATOM | 5986 | C | LYS | E | 209 | −1.899 | 19.711 | 44.170 | 1.00 | 33.52 | E | C |
| ATOM | 5987 | O | LYS | E | 209 | −1.548 | 20.260 | 43.123 | 1.00 | 34.53 | E | O |
| ATOM | 5988 | N | MET | E | 210 | −1.579 | 20.171 | 45.372 | 1.00 | 32.42 | E | N |
| ATOM | 5989 | CA | MET | E | 210 | −0.770 | 21.364 | 45.546 | 1.00 | 30.92 | E | C |
| ATOM | 5990 | CB | MET | E | 210 | −0.779 | 21.787 | 47.014 | 1.00 | 32.14 | E | C |
| ATOM | 5991 | CG | MET | E | 210 | −0.445 | 23.250 | 47.244 | 1.00 | 35.25 | E | C |
| ATOM | 5992 | SD | MET | E | 210 | −1.893 | 24.333 | 47.297 | 1.00 | 33.75 | E | S |
| ATOM | 5993 | CE | MET | E | 210 | −3.185 | 23.178 | 46.996 | 1.00 | 27.88 | E | C |
| ATOM | 5994 | C | MET | E | 210 | 0.654 | 21.060 | 45.117 | 1.00 | 30.51 | E | C |
| ATOM | 5995 | O | MET | E | 210 | 1.144 | 19.952 | 45.317 | 1.00 | 29.81 | E | O |
| ATOM | 5996 | N | LYS | E | 211 | 1.313 | 22.042 | 44.518 | 1.00 | 31.94 | E | N |
| ATOM | 5997 | CA | LYS | E | 211 | 2.695 | 21.880 | 44.084 | 1.00 | 32.48 | E | C |
| ATOM | 5998 | CB | LYS | E | 211 | 2.755 | 21.376 | 42.647 | 1.00 | 33.83 | E | C |
| ATOM | 5999 | CG | LYS | E | 211 | 4.120 | 20.843 | 42.257 | 1.00 | 34.43 | E | C |
| ATOM | 6000 | CD | LYS | E | 211 | 4.585 | 21.461 | 40.960 | 1.00 | 38.14 | E | C |
| ATOM | 6001 | CE | LYS | E | 211 | 4.766 | 20.409 | 39.889 | 1.00 | 39.32 | E | C |
| ATOM | 6002 | NZ | LYS | E | 211 | 6.119 | 19.795 | 39.972 | 1.00 | 43.38 | E | N |
| ATOM | 6003 | C | LYS | E | 211 | 3.415 | 23.213 | 44.184 | 1.00 | 33.34 | E | C |
| ATOM | 6004 | O | LYS | E | 211 | 3.172 | 24.123 | 43.388 | 1.00 | 36.04 | E | O |
| ATOM | 6005 | N | ASP | E | 212 | 4.289 | 23.326 | 45.177 | 1.00 | 32.39 | E | N |
| ATOM | 6006 | CA | ASP | E | 212 | 5.052 | 24.548 | 45.404 | 1.00 | 31.90 | E | C |
| ATOM | 6007 | CB | ASP | E | 212 | 6.071 | 24.755 | 44.278 | 1.00 | 33.78 | E | C |
| ATOM | 6008 | CG | ASP | E | 212 | 7.190 | 23.726 | 44.311 | 1.00 | 36.07 | E | C |
| ATOM | 6009 | OD1 | ASP | E | 212 | 7.512 | 23.216 | 45.408 | 1.00 | 36.65 | E | O |
| ATOM | 6010 | OD2 | ASP | E | 212 | 7.751 | 23.426 | 43.236 | 1.00 | 40.39 | E | O |
| ATOM | 6011 | C | ASP | E | 212 | 4.173 | 25.788 | 45.548 | 1.00 | 29.18 | E | C |
| ATOM | 6012 | O | ASP | E | 212 | 4.515 | 26.864 | 45.060 | 1.00 | 28.72 | E | O |
| ATOM | 6013 | N | GLY | E | 213 | 3.038 | 25.629 | 46.220 | 1.00 | 27.86 | E | N |
| ATOM | 6014 | CA | GLY | E | 213 | 2.147 | 26.752 | 46.446 | 1.00 | 24.07 | E | C |
| ATOM | 6015 | C | GLY | E | 213 | 1.035 | 26.938 | 45.439 | 1.00 | 23.79 | E | C |
| ATOM | 6016 | O | GLY | E | 213 | 0.212 | 27.846 | 45.584 | 1.00 | 24.43 | E | O |
| ATOM | 6017 | N | VAL | E | 214 | 0.989 | 26.086 | 44.422 | 1.00 | 22.28 | E | N |
| ATOM | 6018 | CA | VAL | E | 214 | −0.042 | 26.216 | 43.396 | 1.00 | 23.44 | E | C |
| ATOM | 6019 | CB | VAL | E | 214 | 0.590 | 26.652 | 42.037 | 1.00 | 24.47 | E | C |
| ATOM | 6020 | CG1 | VAL | E | 214 | −0.491 | 26.783 | 40.961 | 1.00 | 23.08 | E | C |
| ATOM | 6021 | CG2 | VAL | E | 214 | 1.326 | 27.986 | 42.205 | 1.00 | 22.59 | E | C |
| ATOM | 6022 | C | VAL | E | 214 | −0.827 | 24.925 | 43.195 | 1.00 | 22.42 | E | C |
| ATOM | 6023 | O | VAL | E | 214 | −0.262 | 23.836 | 43.257 | 1.00 | 26.64 | E | O |
| ATOM | 6024 | N | VAL | E | 215 | −2.129 | 25.047 | 42.961 | 1.00 | 20.85 | E | N |
| ATOM | 6025 | CA | VAL | E | 215 | −2.966 | 23.872 | 42.734 | 1.00 | 21.98 | E | C |
| ATOM | 6026 | CB | VAL | E | 215 | −4.469 | 24.191 | 42.886 | 1.00 | 21.99 | E | C |
| ATOM | 6027 | CG1 | VAL | E | 215 | −5.301 | 22.957 | 42.551 | 1.00 | 18.43 | E | C |
| ATOM | 6028 | CG2 | VAL | E | 215 | −4.766 | 24.669 | 44.306 | 1.00 | 20.76 | E | C |
| ATOM | 6029 | C | VAL | E | 215 | −2.745 | 23.356 | 41.316 | 1.00 | 24.48 | E | C |
| ATOM | 6030 | O | VAL | E | 215 | −3.015 | 24.061 | 40.347 | 1.00 | 22.71 | E | O |
| ATOM | 6031 | N | TYR | E | 216 | −2.245 | 22.127 | 41.202 | 1.00 | 27.49 | E | N |
| ATOM | 6032 | CA | TYR | E | 216 | −2.000 | 21.514 | 39.899 | 1.00 | 27.09 | E | C |
| ATOM | 6033 | CB | TYR | E | 216 | −0.619 | 20.866 | 39.864 | 1.00 | 27.10 | E | C |
| ATOM | 6034 | CG | TYR | E | 216 | 0.469 | 21.798 | 39.390 | 1.00 | 28.05 | E | C |
| ATOM | 6035 | CD1 | TYR | E | 216 | 1.149 | 21.559 | 38.196 | 1.00 | 27.65 | E | C |
| ATOM | 6036 | CE1 | TYR | E | 216 | 2.167 | 22.410 | 37.763 | 1.00 | 26.35 | E | C |
| ATOM | 6037 | CD2 | TYR | E | 216 | 0.831 | 22.916 | 40.144 | 1.00 | 28.87 | E | C |
| ATOM | 6038 | CE2 | TYR | E | 216 | 1.844 | 23.771 | 39.720 | 1.00 | 28.29 | E | C |
| ATOM | 6039 | CZ | TYR | E | 216 | 2.509 | 23.510 | 38.529 | 1.00 | 28.02 | E | C |
| ATOM | 6040 | OH | TYR | E | 216 | 3.519 | 24.349 | 38.112 | 1.00 | 30.19 | E | O |
| ATOM | 6041 | C | TYR | E | 216 | −3.058 | 20.463 | 39.613 | 1.00 | 28.29 | E | C |
| ATOM | 6042 | O | TYR | E | 216 | −3.494 | 19.749 | 40.516 | 1.00 | 25.73 | E | O |
| ATOM | 6043 | N | ILE | E | 217 | −3.469 | 20.374 | 38.352 | 1.00 | 32.17 | E | N |
| ATOM | 6044 | CA | ILE | E | 217 | −4.494 | 19.415 | 37.955 | 1.00 | 36.47 | E | C |
| ATOM | 6045 | CB | ILE | E | 217 | −5.594 | 20.088 | 37.105 | 1.00 | 35.63 | E | C |
| ATOM | 6046 | CG2 | ILE | E | 217 | −6.764 | 19.137 | 36.928 | 1.00 | 34.07 | E | C |
| ATOM | 6047 | CG1 | ILE | E | 217 | −6.058 | 21.384 | 37.779 | 1.00 | 35.28 | E | C |
| ATOM | 6048 | CD1 | ILE | E | 217 | −6.033 | 22.596 | 36.852 | 1.00 | 35.31 | E | C |
| ATOM | 6049 | C | ILE | E | 217 | −3.918 | 18.251 | 37.157 | 1.00 | 38.85 | E | C |
| ATOM | 6050 | O | ILE | E | 217 | −3.261 | 18.446 | 36.127 | 1.00 | 39.57 | E | O |
| ATOM | 6051 | N | TYR | E | 218 | −4.170 | 17.039 | 37.646 | 1.00 | 40.18 | E | N |
| ATOM | 6052 | CA | TYR | E | 218 | −3.694 | 15.833 | 36.990 | 1.00 | 40.30 | E | C |
| ATOM | 6053 | CB | TYR | E | 218 | −2.898 | 14.982 | 37.972 | 1.00 | 36.53 | E | C |
| ATOM | 6054 | CG | TYR | E | 218 | −1.658 | 15.693 | 38.454 | 1.00 | 36.47 | E | C |
| ATOM | 6055 | CD1 | TYR | E | 218 | −0.477 | 15.647 | 37.715 | 1.00 | 36.13 | E | C |
| ATOM | 6056 | CE1 | TYR | E | 218 | 0.648 | 16.359 | 38.115 | 1.00 | 35.65 | E | C |
| ATOM | 6057 | CD2 | TYR | E | 218 | −1.681 | 16.468 | 39.616 | 1.00 | 35.74 | E | C |
| ATOM | 6058 | CE2 | TYR | E | 218 | −0.561 | 17.184 | 40.025 | 1.00 | 36.11 | E | C |
| ATOM | 6059 | CZ | TYR | E | 218 | 0.597 | 17.127 | 39.268 | 1.00 | 36.92 | E | C |
| ATOM | 6060 | OH | TYR | E | 218 | 1.704 | 17.848 | 39.659 | 1.00 | 39.35 | E | O |
| ATOM | 6061 | C | TYR | E | 218 | −4.896 | 15.074 | 36.462 | 1.00 | 44.45 | E | C |
| ATOM | 6062 | O | TYR | E | 218 | −5.817 | 14.742 | 37.210 | 1.00 | 43.74 | E | O |
| ATOM | 6063 | N | ALA | E | 219 | −4.881 | 14.825 | 35.157 | 1.00 | 49.65 | E | N |
| ATOM | 6064 | CA | ALA | E | 219 | −5.964 | 14.126 | 34.481 | 1.00 | 54.31 | E | C |
| ATOM | 6065 | CB | ALA | E | 219 | −5.551 | 13.781 | 33.048 | 1.00 | 54.87 | E | C |
| ATOM | 6066 | C | ALA | E | 219 | −6.373 | 12.867 | 35.221 | 1.00 | 56.87 | E | C |
| ATOM | 6067 | O | ALA | E | 219 | −5.526 | 12.041 | 35.549 | 1.00 | 57.34 | E | O |
| ATOM | 6068 | N | ASN | E | 220 | −7.677 | 12.752 | 35.473 | 1.00 | 60.61 | E | N |
| ATOM | 6069 | CA | ASN | E | 220 | −8.312 | 11.619 | 36.159 | 1.00 | 63.74 | E | C |
| ATOM | 6070 | CB | ASN | E | 220 | −9.473 | 11.079 | 35.300 | 1.00 | 64.64 | E | C |
| ATOM | 6071 | CG | ASN | E | 220 | −9.688 | 11.884 | 34.015 | 1.00 | 66.23 | E | C |
| ATOM | 6072 | OD1 | ASN | E | 220 | −10.786 | 12.382 | 33.760 | 1.00 | 67.99 | E | O |
| ATOM | 6073 | ND2 | ASN | E | 220 | −8.639 | 12.008 | 33.203 | 1.00 | 66.47 | E | N |
| ATOM | 6074 | C | ASN | E | 220 | −7.360 | 10.474 | 36.504 | 1.00 | 64.26 | E | C |
| ATOM | 6075 | O | ASN | E | 220 | −7.621 | 9.308 | 36.184 | 1.00 | 65.61 | E | O |
| ATOM | 6076 | N | GLU | E | 221 | −6.268 | 10.806 | 37.182 | 1.00 | 63.12 | E | N |
| ATOM | 6077 | CA | GLU | E | 221 | −5.279 | 9.806 | 37.536 | 1.00 | 62.36 | E | C |
| ATOM | 6078 | CB | GLU | E | 221 | −4.295 | 9.599 | 36.381 | 1.00 | 63.33 | E | C |
| ATOM | 6079 | CG | GLU | E | 221 | −4.501 | 8.333 | 35.584 | 1.00 | 65.45 | E | C |
| ATOM | 6080 | CD | GLU | E | 221 | −3.677 | 8.317 | 34.304 | 1.00 | 69.64 | E | C |
| ATOM | 6081 | OE1 | GLU | E | 221 | −2.451 | 8.560 | 34.381 | 1.00 | 70.00 | E | O |
| ATOM | 6082 | OE2 | GLU | E | 221 | −4.254 | 8.065 | 33.222 | 1.00 | 70.20 | E | O |
| ATOM | 6083 | C | GLU | E | 221 | −4.497 | 10.238 | 38.754 | 1.00 | 61.25 | E | C |
| ATOM | 6084 | O | GLU | E | 221 | −3.849 | 11.288 | 38.747 | 1.00 | 59.77 | E | O |
| ATOM | 6085 | N | ALA | E | 222 | −4.559 | 9.427 | 39.801 | 1.00 | 60.22 | E | N |
| ATOM | 6086 | CA | ALA | E | 222 | −3.799 | 9.719 | 41.000 | 1.00 | 59.93 | E | C |
| ATOM | 6087 | CB | ALA | E | 222 | −4.199 | 8.775 | 42.126 | 1.00 | 59.11 | E | C |
| ATOM | 6088 | C | ALA | E | 222 | −2.346 | 9.487 | 40.578 | 1.00 | 59.82 | E | C |
| ATOM | 6089 | O | ALA | E | 222 | −1.435 | 9.466 | 41.403 | 1.00 | 59.61 | E | O |
| ATOM | 6090 | N | ALA | E | 223 | −2.158 | 9.303 | 39.272 | 1.00 | 60.55 | E | N |
| ATOM | 6091 | CA | ALA | E | 223 | −0.845 | 9.101 | 38.675 | 1.00 | 62.51 | E | C |
| ATOM | 6092 | CB | ALA | E | 223 | −0.989 | 8.551 | 37.264 | 1.00 | 61.08 | E | C |
| ATOM | 6093 | C | ALA | E | 223 | −0.126 | 10.449 | 38.643 | 1.00 | 64.99 | E | C |
| ATOM | 6094 | O | ALA | E | 223 | 0.562 | 10.791 | 37.674 | 1.00 | 64.16 | E | O |
| ATOM | 6095 | N | ALA | E | 224 | −0.327 | 11.223 | 39.707 | 1.00 | 65.61 | E | N |
| ATOM | 6096 | CA | ALA | E | 224 | 0.309 | 12.520 | 39.859 | 1.00 | 63.98 | E | C |
| ATOM | 6097 | CB | ALA | E | 224 | −0.450 | 13.364 | 40.870 | 1.00 | 62.45 | E | C |
| ATOM | 6098 | C | ALA | E | 224 | 1.705 | 12.208 | 40.373 | 1.00 | 65.32 | E | C |
| ATOM | 6099 | O | ALA | E | 224 | 2.530 | 13.107 | 40.551 | 1.00 | 65.43 | E | O |
| ATOM | 6100 | N | GLY | E | 225 | 1.946 | 10.918 | 40.625 | 1.00 | 65.88 | E | N |
| ATOM | 6101 | CA | GLY | E | 225 | 3.246 | 10.464 | 41.095 | 1.00 | 65.63 | E | C |
| ATOM | 6102 | C | GLY | E | 225 | 4.248 | 10.961 | 40.079 | 1.00 | 66.15 | E | C |
| ATOM | 6103 | O | GLY | E | 225 | 5.304 | 11.498 | 40.420 | 1.00 | 66.22 | E | O |
| ATOM | 6104 | N | LYS | E | 226 | 3.906 | 10.765 | 38.810 | 1.00 | 65.86 | E | N |
| ATOM | 6105 | CA | LYS | E | 226 | 4.734 | 11.251 | 37.723 | 1.00 | 64.83 | E | C |
| ATOM | 6106 | CB | LYS | E | 226 | 4.575 | 10.374 | 36.477 | 1.00 | 66.12 | E | C |
| ATOM | 6107 | CG | LYS | E | 226 | 5.854 | 10.224 | 35.660 | 1.00 | 67.34 | E | C |
| ATOM | 6108 | CD | LYS | E | 226 | 6.674 | 9.020 | 36.117 | 1.00 | 67.57 | E | C |
| ATOM | 6109 | CE | LYS | E | 226 | 7.590 | 8.513 | 35.007 | 1.00 | 68.69 | E | C |
| ATOM | 6110 | NZ | LYS | E | 226 | 6.993 | 7.365 | 34.265 | 1.00 | 69.70 | E | N |
| ATOM | 6111 | C | LYS | E | 226 | 4.149 | 12.637 | 37.470 | 1.00 | 64.75 | E | C |
| ATOM | 6112 | O | LYS | E | 226 | 2.956 | 12.773 | 37.175 | 1.00 | 65.47 | E | O |
| ATOM | 6113 | N | ASP | E | 227 | 4.973 | 13.666 | 37.627 | 1.00 | 62.64 | E | N |
| ATOM | 6114 | CA | ASP | E | 227 | 4.515 | 15.030 | 37.417 | 1.00 | 59.56 | E | C |
| ATOM | 6115 | CB | ASP | E | 227 | 5.647 | 16.010 | 37.702 | 1.00 | 62.20 | E | C |
| ATOM | 6116 | CG | ASP | E | 227 | 5.354 | 16.900 | 38.889 | 1.00 | 64.83 | E | C |
| ATOM | 6117 | OD1 | ASP | E | 227 | 5.969 | 16.678 | 39.960 | 1.00 | 64.44 | E | O |
| ATOM | 6118 | OD2 | ASP | E | 227 | 4.507 | 17.814 | 38.746 | 1.00 | 64.36 | E | O |
| ATOM | 6119 | C | ASP | E | 227 | 4.016 | 15.212 | 35.990 | 1.00 | 57.65 | E | C |
| ATOM | 6120 | O | ASP | E | 227 | 4.715 | 15.760 | 35.138 | 1.00 | 55.78 | E | O |
| ATOM | 6121 | N | GLU | E | 228 | 2.798 | 14.745 | 35.738 | 1.00 | 55.56 | E | N |
| ATOM | 6122 | CA | GLU | E | 228 | 2.203 | 14.846 | 34.414 | 1.00 | 53.25 | E | C |
| ATOM | 6123 | CB | GLU | E | 228 | 2.080 | 13.457 | 33.785 | 1.00 | 53.39 | E | C |
| ATOM | 6124 | CG | GLU | E | 228 | 3.337 | 13.009 | 33.061 | 1.00 | 56.15 | E | C |
| ATOM | 6125 | CD | GLU | E | 228 | 3.526 | 11.502 | 33.083 | 1.00 | 58.23 | E | C |
| ATOM | 6126 | OE1 | GLU | E | 228 | 2.518 | 10.770 | 32.976 | 1.00 | 58.22 | E | O |
| ATOM | 6127 | OE2 | GLU | E | 228 | 4.687 | 11.052 | 33.205 | 1.00 | 59.49 | E | O |
| ATOM | 6128 | C | GLU | E | 228 | 0.833 | 15.495 | 34.508 | 1.00 | 50.98 | E | C |
| ATOM | 6129 | O | GLU | E | 228 | −0.195 | 14.843 | 34.304 | 1.00 | 54.11 | E | O |
| ATOM | 6130 | N | PRO | E | 229 | 0.800 | 16.796 | 34.830 | 1.00 | 46.87 | E | N |
| ATOM | 6131 | CD | PRO | E | 229 | 1.952 | 17.672 | 35.105 | 1.00 | 45.44 | E | C |
| ATOM | 6132 | CA | PRO | E | 229 | −0.476 | 17.504 | 34.943 | 1.00 | 42.55 | E | C |
| ATOM | 6133 | CB | PRO | E | 229 | −0.083 | 18.859 | 35.525 | 1.00 | 42.81 | E | C |
| ATOM | 6134 | CG | PRO | E | 229 | 1.342 | 19.043 | 35.125 | 1.00 | 42.66 | E | C |
| ATOM | 6135 | C | PRO | E | 229 | −1.158 | 17.635 | 33.592 | 1.00 | 40.17 | E | C |
| ATOM | 6136 | O | PRO | E | 229 | −0.521 | 17.488 | 32.551 | 1.00 | 36.48 | E | O |
| ATOM | 6137 | N | LYS | E | 230 | −2.459 | 17.897 | 33.614 | 1.00 | 39.98 | E | N |
| ATOM | 6138 | CA | LYS | E | 230 | −3.213 | 18.063 | 32.384 | 1.00 | 41.51 | E | C |
| ATOM | 6139 | CB | LYS | E | 230 | −4.674 | 18.384 | 32.691 | 1.00 | 43.04 | E | C |
| ATOM | 6140 | CG | LYS | E | 230 | −5.589 | 17.174 | 32.692 | 1.00 | 46.30 | E | C |
| ATOM | 6141 | CD | LYS | E | 230 | −6.087 | 16.873 | 31.293 | 1.00 | 48.84 | E | C |
| ATOM | 6142 | CE | LYS | E | 230 | −7.600 | 16.766 | 31.260 | 1.00 | 50.45 | E | C |
| ATOM | 6143 | NZ | LYS | E | 230 | −8.042 | 15.338 | 31.242 | 1.00 | 53.96 | E | N |
| ATOM | 6144 | C | LYS | E | 230 | −2.594 | 19.226 | 31.628 | 1.00 | 44.44 | E | C |
| ATOM | 6145 | O | LYS | E | 230 | −2.258 | 20.248 | 32.230 | 1.00 | 44.79 | E | O |
| ATOM | 6146 | N | PRO | E | 231 | −2.427 | 19.083 | 30.301 | 1.00 | 46.13 | E | N |
| ATOM | 6147 | CD | PRO | E | 231 | −2.787 | 17.905 | 29.490 | 1.00 | 46.02 | E | C |
| ATOM | 6148 | CA | PRO | E | 231 | −1.841 | 20.144 | 29.479 | 1.00 | 44.82 | E | C |
| ATOM | 6149 | CB | PRO | E | 231 | −2.240 | 19.749 | 28.064 | 1.00 | 45.80 | E | C |
| ATOM | 6150 | CG | PRO | E | 231 | −2.264 | 18.257 | 28.116 | 1.00 | 46.13 | E | C |
| ATOM | 6151 | C | PRO | E | 231 | −2.379 | 21.508 | 29.875 | 1.00 | 44.10 | E | C |
| ATOM | 6152 | O | PRO | E | 231 | −3.594 | 21.724 | 29.912 | 1.00 | 43.77 | E | O |
| ATOM | 6153 | N | LEU | E | 232 | −1.464 | 22.422 | 30.173 | 1.00 | 44.20 | E | N |
| ATOM | 6154 | CA | LEU | E | 232 | −1.836 | 23.766 | 30.591 | 1.00 | 43.22 | E | C |
| ATOM | 6155 | CB | LEU | E | 232 | −2.705 | 23.684 | 31.849 | 1.00 | 40.90 | E | C |
| ATOM | 6156 | CG | LEU | E | 232 | −3.533 | 24.892 | 32.280 | 1.00 | 41.21 | E | C |
| ATOM | 6157 | CD1 | LEU | E | 232 | −4.855 | 24.413 | 32.874 | 1.00 | 39.68 | E | C |
| ATOM | 6158 | CD2 | LEU | E | 232 | −2.751 | 25.706 | 33.300 | 1.00 | 40.25 | E | C |
| ATOM | 6159 | C | LEU | E | 232 | −0.587 | 24.599 | 30.879 | 1.00 | 44.03 | E | C |
| ATOM | 6160 | O | LEU | E | 232 | 0.455 | 24.068 | 31.284 | 1.00 | 42.47 | E | O |
| ATOM | 6161 | N | LEU | E | 233 | −0.693 | 25.904 | 30.651 | 1.00 | 43.86 | E | N |
| ATOM | 6162 | CA | LEU | E | 233 | 0.419 | 26.813 | 30.910 | 1.00 | 42.29 | E | C |
| ATOM | 6163 | CB | LEU | E | 233 | 0.324 | 28.044 | 30.004 | 1.00 | 46.41 | E | C |
| ATOM | 6164 | CG | LEU | E | 233 | −0.952 | 28.882 | 30.182 | 1.00 | 50.54 | E | C |
| ATOM | 6165 | CD1 | LEU | E | 233 | −0.702 | 30.305 | 29.677 | 1.00 | 50.07 | E | C |
| ATOM | 6166 | CD2 | LEU | E | 233 | −2.127 | 28.221 | 29.445 | 1.00 | 48.47 | E | C |
| ATOM | 6167 | C | LEU | E | 233 | 0.301 | 27.234 | 32.370 | 1.00 | 39.73 | E | C |
| ATOM | 6168 | O | LEU | E | 233 | −0.654 | 27.912 | 32.755 | 1.00 | 37.82 | E | O |
| ATOM | 6169 | N | TYR | E | 234 | 1.258 | 26.807 | 33.185 | 1.00 | 36.28 | E | N |
| ATOM | 6170 | CA | TYR | E | 234 | 1.245 | 27.147 | 34.599 | 1.00 | 33.06 | E | C |
| ATOM | 6171 | CB | TYR | E | 234 | 1.692 | 25.941 | 35.436 | 1.00 | 30.99 | E | C |
| ATOM | 6172 | CG | TYR | E | 234 | 0.681 | 24.808 | 35.455 | 1.00 | 32.49 | E | C |
| ATOM | 6173 | CD1 | TYR | E | 234 | 0.604 | 23.901 | 34.397 | 1.00 | 29.65 | E | C |
| ATOM | 6174 | CE1 | TYR | E | 234 | −0.337 | 22.875 | 34.394 | 1.00 | 28.94 | E | C |
| ATOM | 6175 | CD2 | TYR | E | 234 | −0.214 | 24.653 | 36.521 | 1.00 | 29.26 | E | C |
| ATOM | 6176 | CE2 | TYR | E | 234 | −1.162 | 23.627 | 36.527 | 1.00 | 28.20 | E | C |
| ATOM | 6177 | CZ | TYR | E | 234 | −1.217 | 22.743 | 35.457 | 1.00 | 30.44 | E | C |
| ATOM | 6178 | OH | TYR | E | 234 | −2.162 | 21.732 | 35.422 | 1.00 | 34.11 | E | O |
| ATOM | 6179 | C | TYR | E | 234 | 2.170 | 28.333 | 34.846 | 1.00 | 31.96 | E | C |
| ATOM | 6180 | O | TYR | E | 234 | 2.986 | 28.686 | 33.992 | 1.00 | 31.07 | E | O |
| ATOM | 6181 | N | PRO | E | 235 | 2.033 | 28.984 | 36.009 | 1.00 | 30.70 | E | N |
| ATOM | 6182 | CD | PRO | E | 235 | 1.065 | 28.708 | 37.085 | 1.00 | 30.56 | E | C |
| ATOM | 6183 | CA | PRO | E | 235 | 2.886 | 30.130 | 36.322 | 1.00 | 30.12 | E | C |
| ATOM | 6184 | CB | PRO | E | 235 | 2.450 | 30.529 | 37.732 | 1.00 | 30.95 | E | C |
| ATOM | 6185 | CG | PRO | E | 235 | 1.067 | 29.976 | 37.875 | 1.00 | 28.82 | E | C |
| ATOM | 6186 | C | PRO | E | 235 | 4.359 | 29.732 | 36.273 | 1.00 | 30.58 | E | C |
| ATOM | 6187 | O | PRO | E | 235 | 4.713 | 28.611 | 36.630 | 1.00 | 31.63 | E | O |
| ATOM | 6188 | N | ASN | E | 236 | 5.211 | 30.649 | 35.828 | 1.00 | 30.12 | E | N |
| ATOM | 6189 | CA | ASN | E | 236 | 6.645 | 30.392 | 35.746 | 1.00 | 29.25 | E | C |
| ATOM | 6190 | CB | ASN | E | 236 | 7.125 | 30.591 | 34.312 | 1.00 | 31.47 | E | C |
| ATOM | 6191 | CG | ASN | E | 236 | 8.567 | 30.198 | 34.124 | 1.00 | 33.08 | E | C |
| ATOM | 6192 | OD1 | ASN | E | 236 | 9.414 | 30.477 | 34.971 | 1.00 | 35.74 | E | O |
| ATOM | 6193 | ND2 | ASN | E | 236 | 8.859 | 29.545 | 33.006 | 1.00 | 35.41 | E | N |
| ATOM | 6194 | C | ASN | E | 236 | 7.350 | 31.374 | 36.671 | 1.00 | 29.53 | E | C |
| ATOM | 6195 | O | ASN | E | 236 | 7.583 | 32.531 | 36.296 | 1.00 | 28.64 | E | O |
| ATOM | 6196 | N | MET | E | 237 | 7.694 | 30.909 | 37.872 | 1.00 | 28.98 | E | N |
| ATOM | 6197 | CA | MET | E | 237 | 8.331 | 31.764 | 38.861 | 1.00 | 28.29 | E | C |
| ATOM | 6198 | CB | MET | E | 237 | 8.493 | 31.029 | 40.188 | 1.00 | 31.35 | E | C |
| ATOM | 6199 | CG | MET | E | 237 | 8.648 | 31.982 | 41.362 | 1.00 | 34.75 | E | C |
| ATOM | 6200 | SD | MET | E | 237 | 8.846 | 31.142 | 42.927 | 1.00 | 40.08 | E | S |
| ATOM | 6201 | CE | MET | E | 237 | 10.606 | 30.698 | 42.858 | 1.00 | 40.46 | E | C |
| ATOM | 6202 | C | MET | E | 237 | 9.662 | 32.371 | 38.472 | 1.00 | 28.04 | E | C |
| ATOM | 6203 | O | MET | E | 237 | 9.922 | 33.528 | 38.793 | 1.00 | 29.77 | E | O |
| ATOM | 6204 | N | GLU | E | 238 | 10.514 | 31.615 | 37.795 | 1.00 | 28.73 | E | N |
| ATOM | 6205 | CA | GLU | E | 238 | 11.802 | 32.168 | 37.404 | 1.00 | 30.53 | E | C |
| ATOM | 6206 | CB | GLU | E | 238 | 12.669 | 31.116 | 36.716 | 1.00 | 33.59 | E | C |
| ATOM | 6207 | CG | GLU | E | 238 | 14.124 | 31.552 | 36.583 | 1.00 | 44.61 | E | C |
| ATOM | 6208 | CD | GLU | E | 238 | 14.957 | 30.625 | 35.707 | 1.00 | 51.07 | E | C |
| ATOM | 6209 | OE1 | GLU | E | 238 | 15.912 | 31.118 | 35.058 | 1.00 | 53.40 | E | O |
| ATOM | 6210 | OE2 | GLU | E | 238 | 14.661 | 29.408 | 35.672 | 1.00 | 54.34 | E | O |
| ATOM | 6211 | C | GLU | E | 238 | 11.572 | 33.339 | 36.461 | 1.00 | 30.36 | E | C |
| ATOM | 6212 | O | GLU | E | 238 | 12.204 | 34.390 | 36.587 | 1.00 | 31.66 | E | O |
| ATOM | 6213 | N | GLU | E | 239 | 10.656 | 33.152 | 35.520 | 1.00 | 26.71 | E | N |
| ATOM | 6214 | CA | GLU | E | 239 | 10.327 | 34.182 | 34.557 | 1.00 | 25.66 | E | C |
| ATOM | 6215 | CB | GLU | E | 239 | 9.306 | 33.635 | 33.562 | 1.00 | 30.59 | E | C |
| ATOM | 6216 | CG | GLU | E | 239 | 8.863 | 34.621 | 32.494 | 1.00 | 33.44 | E | C |
| ATOM | 6217 | CD | GLU | E | 239 | 7.743 | 34.067 | 31.630 | 1.00 | 36.28 | E | C |
| ATOM | 6218 | OE1 | GLU | E | 239 | 6.984 | 34.872 | 31.048 | 1.00 | 38.74 | E | O |
| ATOM | 6219 | OE2 | GLU | E | 239 | 7.620 | 32.827 | 31.533 | 1.00 | 37.63 | E | O |
| ATOM | 6220 | C | GLU | E | 239 | 9.752 | 35.389 | 35.287 | 1.00 | 25.64 | E | C |
| ATOM | 6221 | O | GLU | E | 239 | 10.093 | 36.532 | 34.985 | 1.00 | 27.28 | E | O |
| ATOM | 6222 | N | PHE | E | 240 | 8.881 | 35.131 | 36.257 | 1.00 | 24.54 | E | N |
| ATOM | 6223 | CA | PHE | E | 240 | 8.258 | 36.200 | 37.029 | 1.00 | 20.95 | E | C |
| ATOM | 6224 | CB | PHE | E | 240 | 7.256 | 35.620 | 38.020 | 1.00 | 18.72 | E | C |
| ATOM | 6225 | CG | PHE | E | 240 | 6.568 | 36.661 | 38.851 | 1.00 | 19.51 | E | C |
| ATOM | 6226 | CD1 | PHE | E | 240 | 7.220 | 37.257 | 39.924 | 1.00 | 18.90 | E | C |
| ATOM | 6227 | CD2 | PHE | E | 240 | 5.268 | 37.053 | 38.558 | 1.00 | 18.33 | E | C |
| ATOM | 6228 | CE1 | PHE | E | 240 | 6.585 | 38.227 | 40.692 | 1.00 | 18.85 | E | C |
| ATOM | 6229 | CE2 | PHE | E | 240 | 4.628 | 38.020 | 39.317 | 1.00 | 19.49 | E | C |
| ATOM | 6230 | CZ | PHE | E | 240 | 5.288 | 38.608 | 40.387 | 1.00 | 18.89 | E | C |
| ATOM | 6231 | C | PHE | E | 240 | 9.276 | 37.036 | 37.793 | 1.00 | 20.37 | E | C |
| ATOM | 6232 | O | PHE | E | 240 | 9.217 | 38.262 | 37.778 | 1.00 | 19.79 | E | O |
| ATOM | 6233 | N | LEU | E | 241 | 10.192 | 36.366 | 38.483 | 1.00 | 20.19 | E | N |
| ATOM | 6234 | CA | LEU | E | 241 | 11.217 | 37.060 | 39.247 | 1.00 | 21.54 | E | C |
| ATOM | 6235 | CB | LEU | E | 241 | 12.040 | 36.056 | 40.051 | 1.00 | 21.91 | E | C |
| ATOM | 6236 | CG | LEU | E | 241 | 11.281 | 35.365 | 41.192 | 1.00 | 24.85 | E | C |
| ATOM | 6237 | CD1 | LEU | E | 241 | 12.083 | 34.178 | 41.708 | 1.00 | 23.63 | E | C |
| ATOM | 6238 | CD2 | LEU | E | 241 | 11.018 | 36.363 | 42.311 | 1.00 | 22.68 | E | C |
| ATOM | 6239 | C | LEU | E | 241 | 12.125 | 37.869 | 38.329 | 1.00 | 23.96 | E | C |
| ATOM | 6240 | O | LEU | E | 241 | 12.684 | 38.890 | 38.736 | 1.00 | 23.37 | E | O |
| ATOM | 6241 | N | ASP | E | 242 | 12.263 | 37.425 | 37.084 | 1.00 | 25.29 | E | N |
| ATOM | 6242 | CA | ASP | E | 242 | 13.107 | 38.134 | 36.127 | 1.00 | 26.04 | E | C |
| ATOM | 6243 | CB | ASP | E | 242 | 13.325 | 37.286 | 34.871 | 1.00 | 31.29 | E | C |
| ATOM | 6244 | CG | ASP | E | 242 | 14.286 | 36.131 | 35.106 | 1.00 | 38.68 | E | C |
| ATOM | 6245 | OD1 | ASP | E | 242 | 14.816 | 36.010 | 36.237 | 1.00 | 42.05 | E | O |
| ATOM | 6246 | OD2 | ASP | E | 242 | 14.509 | 35.342 | 34.158 | 1.00 | 40.91 | E | O |
| ATOM | 6247 | C | ASP | E | 242 | 12.459 | 39.450 | 35.737 | 1.00 | 23.50 | E | C |
| ATOM | 6248 | O | ASP | E | 242 | 13.112 | 40.493 | 35.702 | 1.00 | 21.12 | E | O |
| ATOM | 6249 | N | ASP | E | 243 | 11.168 | 39.389 | 35.436 | 1.00 | 23.14 | E | N |
| ATOM | 6250 | CA | ASP | E | 243 | 10.422 | 40.573 | 35.039 | 1.00 | 22.64 | E | C |
| ATOM | 6251 | CB | ASP | E | 243 | 9.007 | 40.190 | 34.586 | 1.00 | 21.75 | E | C |
| ATOM | 6252 | CG | ASP | E | 243 | 8.995 | 39.460 | 33.249 | 1.00 | 20.82 | E | C |
| ATOM | 6253 | OD1 | ASP | E | 243 | 9.959 | 39.636 | 32.472 | 1.00 | 19.79 | E | O |
| ATOM | 6254 | OD2 | ASP | E | 243 | 8.025 | 38.715 | 32.980 | 1.00 | 17.15 | E | O |
| ATOM | 6255 | C | ASP | E | 243 | 10.339 | 41.536 | 36.210 | 1.00 | 23.12 | E | C |
| ATOM | 6256 | O | ASP | E | 243 | 10.421 | 42.752 | 36.034 | 1.00 | 24.00 | E | O |
| ATOM | 6257 | N | MET | E | 244 | 10.185 | 40.983 | 37.409 | 1.00 | 22.53 | E | N |
| ATOM | 6258 | CA | MET | E | 244 | 10.079 | 41.791 | 38.615 | 1.00 | 21.06 | E | C |
| ATOM | 6259 | CB | MET | E | 244 | 9.741 | 40.918 | 39.816 | 1.00 | 20.61 | E | C |
| ATOM | 6260 | CG | MET | E | 244 | 9.808 | 41.665 | 41.127 | 1.00 | 20.57 | E | C |
| ATOM | 6261 | SD | MET | E | 244 | 9.588 | 40.580 | 42.543 | 1.00 | 25.55 | E | S |
| ATOM | 6262 | CE | MET | E | 244 | 11.253 | 39.934 | 42.729 | 1.00 | 19.95 | E | C |
| ATOM | 6263 | C | MET | E | 244 | 11.358 | 42.546 | 38.905 | 1.00 | 21.41 | E | C |
| ATOM | 6264 | O | MET | E | 244 | 11.320 | 43.725 | 39.252 | 1.00 | 21.86 | E | O |
| ATOM | 6265 | N | ASN | E | 245 | 12.488 | 41.858 | 38.777 | 1.00 | 20.13 | E | N |
| ATOM | 6266 | CA | ASN | E | 245 | 13.783 | 42.474 | 39.030 | 1.00 | 21.24 | E | C |
| ATOM | 6267 | CB | ASN | E | 245 | 14.874 | 41.414 | 38.968 | 1.00 | 21.30 | E | C |
| ATOM | 6268 | CG | ASN | E | 245 | 14.841 | 40.499 | 40.165 | 1.00 | 27.43 | E | C |
| ATOM | 6269 | OD1 | ASN | E | 245 | 14.751 | 40.962 | 41.304 | 1.00 | 28.60 | E | O |
| ATOM | 6270 | ND2 | ASN | E | 245 | 14.904 | 39.193 | 39.922 | 1.00 | 30.43 | E | N |
| ATOM | 6271 | C | ASN | E | 245 | 14.069 | 43.585 | 38.033 | 1.00 | 20.60 | E | C |
| ATOM | 6272 | O | ASN | E | 245 | 14.799 | 44.530 | 38.330 | 1.00 | 20.97 | E | O |
| ATOM | 6273 | N | PHE | E | 246 | 13.480 | 43.461 | 36.849 | 1.00 | 21.91 | E | N |
| ATOM | 6274 | CA | PHE | E | 246 | 13.650 | 44.453 | 35.800 | 1.00 | 21.59 | E | C |
| ATOM | 6275 | CB | PHE | E | 246 | 13.095 | 43.940 | 34.471 | 1.00 | 20.53 | E | C |
| ATOM | 6276 | CG | PHE | E | 246 | 12.782 | 45.036 | 33.504 | 1.00 | 22.35 | E | C |
| ATOM | 6277 | CD1 | PHE | E | 246 | 11.479 | 45.480 | 33.335 | 1.00 | 21.94 | E | C |
| ATOM | 6278 | CD2 | PHE | E | 246 | 13.800 | 45.660 | 32.788 | 1.00 | 23.76 | E | C |
| ATOM | 6279 | CE1 | PHE | E | 246 | 11.195 | 46.525 | 32.477 | 1.00 | 17.91 | E | C |
| ATOM | 6280 | CE2 | PHE | E | 246 | 13.520 | 46.709 | 31.924 | 1.00 | 20.98 | E | C |
| ATOM | 6281 | CZ | PHE | E | 246 | 12.215 | 47.140 | 31.771 | 1.00 | 17.51 | E | C |
| ATOM | 6282 | C | PHE | E | 246 | 12.889 | 45.705 | 36.200 | 1.00 | 20.76 | E | C |
| ATOM | 6283 | O | PHE | E | 246 | 13.410 | 46.814 | 36.120 | 1.00 | 25.08 | E | O |
| ATOM | 6284 | N | LEU | E | 247 | 11.644 | 45.523 | 36.621 | 1.00 | 18.45 | E | N |
| ATOM | 6285 | CA | LEU | E | 247 | 10.817 | 46.645 | 37.031 | 1.00 | 19.27 | E | C |
| ATOM | 6286 | CB | LEU | E | 247 | 9.398 | 46.162 | 37.348 | 1.00 | 17.83 | E | C |
| ATOM | 6287 | CG | LEU | E | 247 | 8.565 | 45.734 | 36.134 | 1.00 | 15.69 | E | C |
| ATOM | 6288 | CD1 | LEU | E | 247 | 7.188 | 45.263 | 36.582 | 1.00 | 12.27 | E | C |
| ATOM | 6289 | CD2 | LEU | E | 247 | 8.447 | 46.906 | 35.176 | 1.00 | 11.80 | E | C |
| ATOM | 6290 | C | LEU | E | 247 | 11.431 | 47.327 | 38.252 | 1.00 | 20.47 | E | C |
| ATOM | 6291 | O | LEU | E | 247 | 11.405 | 48.550 | 38.366 | 1.00 | 21.43 | E | O |
| ATOM | 6292 | N | LEU | E | 248 | 11.993 | 46.534 | 39.157 | 1.00 | 21.98 | E | N |
| ATOM | 6293 | CA | LEU | E | 248 | 12.615 | 47.081 | 40.352 | 1.00 | 22.41 | E | C |
| ATOM | 6294 | CB | LEU | E | 248 | 13.149 | 45.960 | 41.240 | 1.00 | 25.03 | E | C |
| ATOM | 6295 | CG | LEU | E | 248 | 12.573 | 45.827 | 42.653 | 1.00 | 25.37 | E | C |
| ATOM | 6296 | CD1 | LEU | E | 248 | 11.137 | 46.343 | 42.701 | 1.00 | 25.73 | E | C |
| ATOM | 6297 | CD2 | LEU | E | 248 | 12.621 | 44.362 | 43.071 | 1.00 | 25.95 | E | C |
| ATOM | 6298 | C | LEU | E | 248 | 13.757 | 48.001 | 39.961 | 1.00 | 21.83 | E | C |
| ATOM | 6299 | O | LEU | E | 248 | 13.914 | 49.084 | 40.524 | 1.00 | 25.26 | E | O |
| ATOM | 6300 | N | ALA | E | 249 | 14.557 | 47.571 | 38.992 | 1.00 | 21.36 | E | N |
| ATOM | 6301 | CA | ALA | E | 249 | 15.688 | 48.375 | 38.537 | 1.00 | 20.94 | E | C |
| ATOM | 6302 | CB | ALA | E | 249 | 16.549 | 47.558 | 37.583 | 1.00 | 14.17 | E | C |
| ATOM | 6303 | C | ALA | E | 249 | 15.188 | 49.646 | 37.848 | 1.00 | 20.45 | E | C |
| ATOM | 6304 | O | ALA | E | 249 | 15.682 | 50.751 | 38.088 | 1.00 | 17.49 | E | O |
| ATOM | 6305 | N | LEU | E | 250 | 14.181 | 49.470 | 37.003 | 1.00 | 22.23 | E | N |
| ATOM | 6306 | CA | LEU | E | 250 | 13.598 | 50.567 | 36.256 | 1.00 | 21.12 | E | C |
| ATOM | 6307 | CB | LEU | E | 250 | 12.455 | 50.042 | 35.393 | 1.00 | 19.91 | E | C |
| ATOM | 6308 | CG | LEU | E | 250 | 11.926 | 51.016 | 34.344 | 1.00 | 17.89 | E | C |
| ATOM | 6309 | CD1 | LEU | E | 250 | 12.938 | 51.185 | 33.227 | 1.00 | 14.45 | E | C |
| ATOM | 6310 | CD2 | LEU | E | 250 | 10.600 | 50.490 | 33.810 | 1.00 | 16.41 | E | C |
| ATOM | 6311 | C | LEU | E | 250 | 13.101 | 51.721 | 37.115 | 1.00 | 20.34 | E | C |
| ATOM | 6312 | O | LEU | E | 250 | 13.595 | 52.834 | 36.994 | 1.00 | 20.39 | E | O |
| ATOM | 6313 | N | ILE | E | 251 | 12.129 | 51.464 | 37.984 | 1.00 | 21.40 | E | N |
| ATOM | 6314 | CA | ILE | E | 251 | 11.580 | 52.533 | 38.819 | 1.00 | 24.31 | E | C |
| ATOM | 6315 | CB | ILE | E | 251 | 10.479 | 52.008 | 39.785 | 1.00 | 22.70 | E | C |
| ATOM | 6316 | CG2 | ILE | E | 251 | 9.492 | 51.123 | 39.022 | 1.00 | 20.06 | E | C |
| ATOM | 6317 | CG1 | ILE | E | 251 | 11.117 | 51.241 | 40.943 | 1.00 | 24.41 | E | C |
| ATOM | 6318 | CD1 | ILE | E | 251 | 10.140 | 50.392 | 41.733 | 1.00 | 24.60 | E | C |
| ATOM | 6319 | C | ILE | E | 251 | 12.623 | 53.293 | 39.634 | 1.00 | 24.67 | E | C |
| ATOM | 6320 | O | ILE | E | 251 | 12.335 | 54.369 | 40.165 | 1.00 | 24.58 | E | O |
| ATOM | 6321 | N | ALA | E | 252 | 13.831 | 52.747 | 39.728 | 1.00 | 24.94 | E | N |
| ATOM | 6322 | CA | ALA | E | 252 | 14.888 | 53.409 | 40.484 | 1.00 | 25.31 | E | C |
| ATOM | 6323 | CB | ALA | E | 252 | 15.535 | 52.428 | 41.446 | 1.00 | 25.64 | E | C |
| ATOM | 6324 | C | ALA | E | 252 | 15.951 | 54.033 | 39.584 | 1.00 | 27.01 | E | C |
| ATOM | 6325 | O | ALA | E | 252 | 16.943 | 54.568 | 40.079 | 1.00 | 28.62 | E | O |
| ATOM | 6326 | N | GLN | E | 253 | 15.738 | 53.971 | 38.270 | 1.00 | 27.47 | E | N |
| ATOM | 6327 | CA | GLN | E | 253 | 16.675 | 54.532 | 37.302 | 1.00 | 25.25 | E | C |
| ATOM | 6328 | CB | GLN | E | 253 | 16.438 | 53.918 | 35.932 | 1.00 | 28.00 | E | C |
| ATOM | 6329 | CG | GLN | E | 253 | 17.633 | 53.198 | 35.374 | 1.00 | 32.24 | E | C |
| ATOM | 6330 | CD | GLN | E | 253 | 17.245 | 52.253 | 34.267 | 1.00 | 36.43 | E | C |
| ATOM | 6331 | OE1 | GLN | E | 253 | 17.317 | 51.036 | 34.423 | 1.00 | 39.75 | E | O |
| ATOM | 6332 | NE2 | GLN | E | 253 | 16.822 | 52.806 | 33.136 | 1.00 | 40.84 | E | N |
| ATOM | 6333 | C | GLN | E | 253 | 16.527 | 56.043 | 37.204 | 1.00 | 24.38 | E | C |
| ATOM | 6334 | O | GLN | E | 253 | 15.448 | 56.553 | 36.909 | 1.00 | 25.23 | E | O |
| ATOM | 6335 | N | GLY | E | 254 | 17.626 | 56.751 | 37.437 | 1.00 | 24.11 | E | N |
| ATOM | 6336 | CA | GLY | E | 254 | 17.617 | 58.201 | 37.395 | 1.00 | 19.16 | E | C |
| ATOM | 6337 | C | GLY | E | 254 | 16.919 | 58.827 | 36.208 | 1.00 | 20.83 | E | C |
| ATOM | 6338 | O | GLY | E | 254 | 15.950 | 59.560 | 36.385 | 1.00 | 21.15 | E | O |
| ATOM | 6339 | N | PRO | E | 255 | 17.391 | 58.565 | 34.979 | 1.00 | 19.84 | E | N |
| ATOM | 6340 | CD | PRO | E | 255 | 18.553 | 57.718 | 34.668 | 1.00 | 15.11 | E | C |
| ATOM | 6341 | CA | PRO | E | 255 | 16.792 | 59.123 | 33.760 | 1.00 | 17.40 | E | C |
| ATOM | 6342 | CB | PRO | E | 255 | 17.630 | 58.512 | 32.640 | 1.00 | 15.74 | E | C |
| ATOM | 6343 | CG | PRO | E | 255 | 18.914 | 58.155 | 33.292 | 1.00 | 11.88 | E | C |
| ATOM | 6344 | C | PRO | E | 255 | 15.302 | 58.846 | 33.586 | 1.00 | 18.22 | E | C |
| ATOM | 6345 | O | PRO | E | 255 | 14.554 | 59.720 | 33.163 | 1.00 | 20.94 | E | O |
| ATOM | 6346 | N | VAL | E | 256 | 14.865 | 57.633 | 33.901 | 1.00 | 17.63 | E | N |
| ATOM | 6347 | CA | VAL | E | 256 | 13.451 | 57.288 | 33.767 | 1.00 | 17.06 | E | C |
| ATOM | 6348 | CB | VAL | E | 256 | 13.217 | 55.777 | 33.976 | 1.00 | 14.36 | E | C |
| ATOM | 6349 | CG1 | VAL | E | 256 | 11.758 | 55.444 | 33.749 | 1.00 | 7.21 | E | C |
| ATOM | 6350 | CG2 | VAL | E | 256 | 14.095 | 54.980 | 33.021 | 1.00 | 12.09 | E | C |
| ATOM | 6351 | C | VAL | E | 256 | 12.618 | 58.058 | 34.786 | 1.00 | 20.56 | E | C |
| ATOM | 6352 | O | VAL | E | 256 | 11.471 | 58.433 | 34.516 | 1.00 | 21.69 | E | O |
| ATOM | 6353 | N | LYS | E | 257 | 13.198 | 58.284 | 35.964 | 1.00 | 21.38 | E | N |
| ATOM | 6354 | CA | LYS | E | 257 | 12.521 | 59.015 | 37.031 | 1.00 | 19.87 | E | C |
| ATOM | 6355 | CB | LYS | E | 257 | 13.383 | 59.028 | 38.293 | 1.00 | 22.89 | E | C |
| ATOM | 6356 | CG | LYS | E | 257 | 12.856 | 58.167 | 39.430 | 1.00 | 23.73 | E | C |
| ATOM | 6357 | CD | LYS | E | 257 | 13.972 | 57.378 | 40.085 | 1.00 | 26.19 | E | C |
| ATOM | 6358 | CE | LYS | E | 257 | 14.557 | 58.126 | 41.272 | 1.00 | 30.24 | E | C |
| ATOM | 6359 | NZ | LYS | E | 257 | 16.060 | 58.136 | 41.267 | 1.00 | 31.39 | E | N |
| ATOM | 6360 | C | LYS | E | 257 | 12.289 | 60.439 | 36.572 | 1.00 | 18.56 | E | C |
| ATOM | 6361 | O | LYS | E | 257 | 11.209 | 60.997 | 36.756 | 1.00 | 19.92 | E | O |
| ATOM | 6362 | N | THR | E | 258 | 13.314 | 61.023 | 35.964 | 1.00 | 18.68 | E | N |
| ATOM | 6363 | CA | THR | E | 258 | 13.236 | 62.391 | 35.473 | 1.00 | 19.30 | E | C |
| ATOM | 6364 | CB | THR | E | 258 | 14.612 | 62.877 | 35.005 | 1.00 | 21.16 | E | C |
| ATOM | 6365 | OG1 | THR | E | 258 | 15.540 | 62.779 | 36.095 | 1.00 | 25.52 | E | O |
| ATOM | 6366 | CG2 | THR | E | 258 | 14.534 | 64.328 | 34.548 | 1.00 | 22.43 | E | C |
| ATOM | 6367 | C | THR | E | 258 | 12.236 | 62.561 | 34.335 | 1.00 | 16.39 | E | C |
| ATOM | 6368 | O | THR | E | 258 | 11.390 | 63.452 | 34.375 | 1.00 | 16.92 | E | O |
| ATOM | 6369 | N | TYR | E | 259 | 12.328 | 61.707 | 33.322 | 1.00 | 14.65 | E | N |
| ATOM | 6370 | CA | TYR | E | 259 | 11.414 | 61.788 | 32.188 | 1.00 | 12.76 | E | C |
| ATOM | 6371 | CB | TYR | E | 259 | 11.728 | 60.685 | 31.168 | 1.00 | 13.03 | E | C |
| ATOM | 6372 | CG | TYR | E | 259 | 10.773 | 60.662 | 29.991 | 1.00 | 16.89 | E | C |
| ATOM | 6373 | CD1 | TYR | E | 259 | 9.741 | 59.731 | 29.926 | 1.00 | 15.64 | E | C |
| ATOM | 6374 | CE1 | TYR | E | 259 | 8.858 | 59.714 | 28.863 | 1.00 | 16.15 | E | C |
| ATOM | 6375 | CD2 | TYR | E | 259 | 10.891 | 61.583 | 28.948 | 1.00 | 16.15 | E | C |
| ATOM | 6376 | CE2 | TYR | E | 259 | 10.010 | 61.571 | 27.881 | 1.00 | 14.47 | E | C |
| ATOM | 6377 | CZ | TYR | E | 259 | 8.996 | 60.632 | 27.847 | 1.00 | 16.35 | E | C |
| ATOM | 6378 | OH | TYR | E | 259 | 8.111 | 60.598 | 26.794 | 1.00 | 21.53 | E | O |
| ATOM | 6379 | C | TYR | E | 259 | 9.962 | 61.674 | 32.645 | 1.00 | 12.58 | E | C |
| ATOM | 6380 | O | TYR | E | 259 | 9.149 | 62.558 | 32.376 | 1.00 | 8.10 | E | O |
| ATOM | 6381 | N | THR | E | 260 | 9.641 | 60.586 | 33.342 | 1.00 | 13.75 | E | N |
| ATOM | 6382 | CA | THR | E | 260 | 8.275 | 60.361 | 33.819 | 1.00 | 13.85 | E | C |
| ATOM | 6383 | CB | THR | E | 260 | 8.157 | 59.009 | 34.568 | 1.00 | 15.40 | E | C |
| ATOM | 6384 | OG1 | THR | E | 260 | 9.043 | 58.989 | 35.693 | 1.00 | 15.91 | E | O |
| ATOM | 6385 | CG2 | THR | E | 260 | 8.524 | 57.859 | 33.637 | 1.00 | 11.98 | E | C |
| ATOM | 6386 | C | THR | E | 260 | 7.791 | 61.499 | 34.720 | 1.00 | 15.28 | E | C |
| ATOM | 6387 | O | THR | E | 260 | 6.617 | 61.870 | 34.690 | 1.00 | 12.35 | E | O |
| ATOM | 6388 | N | HIS | E | 261 | 8.700 | 62.067 | 35.508 | 1.00 | 17.09 | E | N |
| ATOM | 6389 | CA | HIS | E | 261 | 8.350 | 63.174 | 36.391 | 1.00 | 16.54 | E | C |
| ATOM | 6390 | CB | HIS | E | 261 | 9.542 | 63.545 | 37.276 | 1.00 | 19.77 | E | C |
| ATOM | 6391 | CG | HIS | E | 261 | 9.245 | 64.632 | 38.262 | 1.00 | 21.04 | E | C |
| ATOM | 6392 | CD2 | HIS | E | 261 | 8.340 | 64.701 | 39.264 | 1.00 | 20.47 | E | C |
| ATOM | 6393 | ND1 | HIS | E | 261 | 9.916 | 65.837 | 38.266 | 1.00 | 21.17 | E | N |
| ATOM | 6394 | CE1 | HIS | E | 261 | 9.435 | 66.601 | 39.229 | 1.00 | 20.01 | E | C |
| ATOM | 6395 | NE2 | HIS | E | 261 | 8.478 | 65.935 | 39.850 | 1.00 | 19.98 | E | N |
| ATOM | 6396 | C | HIS | E | 261 | 7.939 | 64.380 | 35.557 | 1.00 | 14.99 | E | C |
| ATOM | 6397 | O | HIS | E | 261 | 6.978 | 65.071 | 35.882 | 1.00 | 17.01 | E | O |
| ATOM | 6398 | N | ARG | E | 262 | 8.673 | 64.627 | 34.478 | 1.00 | 16.27 | E | N |
| ATOM | 6399 | CA | ARG | E | 262 | 8.386 | 65.748 | 33.582 | 1.00 | 16.84 | E | C |
| ATOM | 6400 | CB | ARG | E | 262 | 9.528 | 65.912 | 32.574 | 1.00 | 18.66 | E | C |
| ATOM | 6401 | CG | AEG | E | 262 | 9.856 | 67.354 | 32.245 | 1.00 | 27.86 | E | C |
| ATOM | 6402 | CD | ARG | E | 262 | 10.887 | 67.454 | 31.133 | 1.00 | 32.12 | E | C |
| ATOM | 6403 | NE | ARG | E | 262 | 12.129 | 66.776 | 31.483 | 1.00 | 38.52 | E | N |
| ATOM | 6404 | CZ | ARG | E | 262 | 12.736 | 65.882 | 30.707 | 1.00 | 41.20 | E | C |
| ATOM | 6405 | NH1 | ARG | E | 262 | 12.210 | 65.560 | 29.528 | 1.00 | 39.55 | E | N |
| ATOM | 6406 | NH2 | ARG | E | 262 | 13.868 | 65.311 | 31.107 | 1.00 | 39.39 | E | N |
| ATOM | 6407 | C | ARG | E | 262 | 7.055 | 65.580 | 32.837 | 1.00 | 13.55 | E | C |
| ATOM | 6408 | O | ARG | E | 262 | 6.301 | 66.546 | 32.662 | 1.00 | 9.65 | E | O |
| ATOM | 6409 | N | ARG | E | 263 | 6.765 | 64.356 | 32.400 | 1.00 | 11.40 | E | N |
| ATOM | 6410 | CA | ARG | E | 263 | 5.524 | 64.081 | 31.686 | 1.00 | 8.82 | E | C |
| ATOM | 6411 | CB | ARG | E | 263 | 5.553 | 62.668 | 31.112 | 1.00 | 8.22 | E | C |
| ATOM | 6412 | CG | ARG | E | 263 | 6.733 | 62.372 | 30.190 | 1.00 | 8.44 | E | C |
| ATOM | 6413 | CD | ARG | E | 263 | 6.866 | 63.405 | 29.071 | 1.00 | 5.96 | E | C |
| ATOM | 6414 | NE | ARG | E | 263 | 5.577 | 63.752 | 28.489 | 1.00 | 7.15 | E | N |
| ATOM | 6415 | CZ | ARG | E | 263 | 5.330 | 64.890 | 27.847 | 1.00 | 8.59 | E | C |
| ATOM | 6416 | NH1 | ARG | E | 263 | 6.291 | 65.792 | 27.704 | 1.00 | 4.36 | E | N |
| ATOM | 6417 | NH2 | ARG | E | 263 | 4.118 | 65.131 | 27.356 | 1.00 | 6.57 | E | N |
| ATOM | 6418 | C | ARG | E | 263 | 4.314 | 64.252 | 32.605 | 1.00 | 11.58 | E | C |
| ATOM | 6419 | O | ARG | E | 263 | 3.269 | 64.761 | 32.189 | 1.00 | 15.28 | E | O |
| ATOM | 6420 | N | LEU | E | 264 | 4.461 | 63.829 | 33.859 | 1.00 | 12.73 | E | N |
| ATOM | 6421 | CA | LEU | E | 264 | 3.389 | 63.947 | 34.850 | 1.00 | 10.68 | E | C |
| ATOM | 6422 | CB | LEU | E | 264 | 3.780 | 63.216 | 36.134 | 1.00 | 7.40 | E | C |
| ATOM | 6423 | CG | LEU | E | 264 | 3.737 | 61.687 | 36.044 | 1.00 | 7.91 | E | C |
| ATOM | 6424 | CD1 | LEU | E | 264 | 4.544 | 61.070 | 37.193 | 1.00 | 5.96 | E | C |
| ATOM | 6425 | CD2 | LEU | E | 264 | 2.285 | 61.221 | 36.077 | 1.00 | 3.15 | E | C |
| ATOM | 6426 | C | LEU | E | 264 | 3.107 | 65.418 | 35.150 | 1.00 | 10.46 | E | C |
| ATOM | 6427 | O | LEU | E | 264 | 1.965 | 65.819 | 35.351 | 1.00 | 8.66 | E | O |
| ATOM | 6428 | N | LYS | E | 265 | 4.156 | 66.226 | 35.178 | 1.00 | 12.72 | E | N |
| ATOM | 6429 | CA | LYS | E | 265 | 3.998 | 67.655 | 35.427 | 1.00 | 12.77 | E | C |
| ATOM | 6430 | CB | LYS | E | 265 | 5.359 | 68.335 | 35.568 | 1.00 | 14.35 | E | C |
| ATOM | 6431 | CG | LYS | E | 265 | 5.849 | 68.474 | 37.003 | 1.00 | 18.84 | E | C |
| ATOM | 6432 | CD | LYS | E | 265 | 7.372 | 68.500 | 37.073 | 1.00 | 24.44 | E | C |
| ATOM | 6433 | CE | LYS | E | 265 | 7.929 | 69.902 | 36.867 | 1.00 | 26.93 | E | C |
| ATOM | 6434 | NZ | LYS | E | 265 | 9.135 | 69.901 | 35.983 | 1.00 | 33.01 | E | N |
| ATOM | 6435 | C | LYS | E | 265 | 3.266 | 68.244 | 34.236 | 1.00 | 13.38 | E | C |
| ATOM | 6436 | O | LYS | E | 265 | 2.435 | 69.136 | 34.385 | 1.00 | 18.89 | E | O |
| ATOM | 6437 | N | PHE | E | 266 | 3.568 | 67.736 | 33.046 | 1.00 | 14.21 | E | N |
| ATOM | 6438 | CA | PHE | E | 266 | 2.915 | 68.235 | 31.843 | 1.00 | 12.13 | E | C |
| ATOM | 6439 | CB | PHE | E | 266 | 3.577 | 67.677 | 30.577 | 1.00 | 11.73 | E | C |
| ATOM | 6440 | CG | PHE | E | 266 | 2.879 | 68.093 | 29.312 | 1.00 | 12.04 | E | C |
| ATOM | 6441 | CD1 | PHE | E | 266 | 3.134 | 69.338 | 28.740 | 1.00 | 12.38 | E | C |
| ATOM | 6442 | CD2 | PHE | E | 266 | 1.917 | 67.273 | 28.727 | 1.00 | 10.07 | E | C |
| ATOM | 6443 | CE1 | PHE | E | 266 | 2.435 | 69.764 | 27.604 | 1.00 | 14.33 | E | C |
| ATOM | 6444 | CE2 | PHE | E | 266 | 1.214 | 67.691 | 27.591 | 1.00 | 12.10 | E | C |
| ATOM | 6445 | CZ | PHE | E | 266 | 1.469 | 68.937 | 27.029 | 1.00 | 9.71 | E | C |
| ATOM | 6446 | C | PHE | E | 266 | 1.446 | 67.855 | 31.849 | 1.00 | 10.88 | E | C |
| ATOM | 6447 | O | PHE | E | 266 | 0.578 | 68.674 | 31.524 | 1.00 | 10.31 | E | O |
| ATOM | 6448 | N | LEU | E | 267 | 1.166 | 66.605 | 32.203 | 1.00 | 9.33 | E | N |
| ATOM | 6449 | CA | LEU | E | 267 | −0.216 | 66.136 | 32.259 | 1.00 | 9.74 | E | C |
| ATOM | 6450 | CB | LEU | E | 267 | −0.253 | 64.698 | 32.779 | 1.00 | 11.47 | E | C |
| ATOM | 6451 | CG | LEU | E | 267 | −0.492 | 63.532 | 31.805 | 1.00 | 15.22 | E | C |
| ATOM | 6452 | CD1 | LEU | E | 267 | −0.289 | 63.964 | 30.370 | 1.00 | 13.95 | E | C |
| ATOM | 6453 | CD2 | LEU | E | 267 | 0.451 | 62.400 | 32.143 | 1.00 | 13.97 | E | C |
| ATOM | 6454 | C | LEU | E | 267 | −1.024 | 67.047 | 33.183 | 1.00 | 9.87 | E | C |
| ATOM | 6455 | O | LEU | E | 267 | −2.172 | 67.382 | 32.905 | 1.00 | 10.08 | E | O |
| ATOM | 6456 | N | SER | E | 268 | −0.401 | 67.449 | 34.285 | 1.00 | 10.49 | E | N |
| ATOM | 6457 | CA | SER | E | 268 | −1.026 | 68.319 | 35.273 | 1.00 | 8.66 | E | C |
| ATOM | 6458 | CB | SER | E | 268 | −0.109 | 68.450 | 36.492 | 1.00 | 10.03 | E | C |
| ATOM | 6459 | OG | SER | E | 268 | −0.714 | 69.224 | 37.514 | 1.00 | 11.55 | E | O |
| ATOM | 6460 | C | SER | E | 268 | −1.319 | 69.703 | 34.711 | 1.00 | 9.07 | E | C |
| ATOM | 6461 | O | SER | E | 268 | −2.465 | 70.147 | 34.718 | 1.00 | 11.84 | E | O |
| ATOM | 6462 | N | SER | E | 269 | −0.283 | 70.390 | 34.235 | 1.00 | 8.55 | E | N |
| ATOM | 6463 | CA | SER | E | 269 | −0.451 | 71.729 | 33.670 | 1.00 | 9.03 | E | C |
| ATOM | 6464 | CB | SER | E | 269 | 0.900 | 72.294 | 33.237 | 1.00 | 10.20 | E | C |
| ATOM | 6465 | OG | SER | E | 269 | 1.725 | 72.584 | 34.349 | 1.00 | 10.55 | E | O |
| ATOM | 6466 | C | SER | E | 269 | −1.404 | 71.739 | 32.471 | 1.00 | 11.09 | E | C |
| ATOM | 6467 | O | SER | E | 269 | −2.196 | 72.676 | 32.310 | 1.00 | 10.29 | E | O |
| ATOM | 6468 | N | LYS | E | 270 | −1.328 | 70.710 | 31.625 | 1.00 | 7.66 | E | N |
| ATOM | 6469 | CA | LYS | E | 270 | −2.210 | 70.643 | 30.466 | 1.00 | 11.31 | E | C |
| ATOM | 6470 | CB | LYS | E | 270 | −1.947 | 69.374 | 29.648 | 1.00 | 9.42 | E | C |
| ATOM | 6471 | CG | LYS | E | 270 | −2.309 | 69.546 | 28.174 | 1.00 | 12.19 | E | C |
| ATOM | 6472 | CD | LYS | E | 270 | −2.509 | 68.221 | 27.449 | 1.00 | 12.22 | E | C |
| ATOM | 6473 | CE | LYS | E | 270 | −3.255 | 68.430 | 26.121 | 1.00 | 13.21 | E | C |
| ATOM | 6474 | NZ | LYS | E | 270 | −3.458 | 67.152 | 25.356 | 1.00 | 9.62 | E | N |
| ATOM | 6475 | C | LYS | E | 270 | −3.688 | 70.697 | 30.861 | 1.00 | 11.08 | E | C |
| ATOM | 6476 | O | LYS | E | 270 | −4.465 | 71.427 | 30.252 | 1.00 | 10.91 | E | O |
| ATOM | 6477 | N | PHE | E | 271 | −4.076 | 69.925 | 31.875 | 1.00 | 12.28 | E | N |
| ATOM | 6478 | CA | PHE | E | 271 | −5.465 | 69.911 | 32.324 | 1.00 | 12.75 | E | C |
| ATOM | 6479 | CB | PHE | E | 271 | −5.665 | 68.866 | 33.420 | 1.00 | 12.06 | E | C |
| ATOM | 6480 | CG | PHE | E | 271 | −7.097 | 68.705 | 33.846 | 1.00 | 11.64 | E | C |
| ATOM | 6481 | CD1 | PHE | E | 271 | −7.975 | 67.924 | 33.097 | 1.00 | 10.40 | E | C |
| ATOM | 6482 | CD2 | PHE | E | 271 | −7.574 | 69.338 | 34.995 | 1.00 | 10.09 | E | C |
| ATOM | 6483 | CE1 | PHE | E | 271 | −9.315 | 67.773 | 33.488 | 1.00 | 13.00 | E | C |
| ATOM | 6484 | CE2 | PHE | E | 271 | −8.911 | 69.193 | 35.392 | 1.00 | 9.58 | E | C |
| ATOM | 6485 | CZ | PHE | E | 271 | −9.784 | 68.410 | 34.638 | 1.00 | 6.87 | E | C |
| ATOM | 6486 | C | PHE | E | 271 | −5.883 | 71.281 | 32.848 | 1.00 | 16.47 | E | C |
| ATOM | 6487 | O | PHE | E | 271 | −7.002 | 71.738 | 32.614 | 1.00 | 19.53 | E | O |
| ATOM | 6488 | N | GLN | E | 272 | −4.984 | 71.941 | 33.561 | 1.00 | 16.00 | E | N |
| ATOM | 6489 | CA | GLN | E | 272 | −5.282 | 73.257 | 34.103 | 1.00 | 17.36 | E | C |
| ATOM | 6490 | CB | GLN | E | 272 | −4.080 | 73.789 | 34.877 | 1.00 | 20.93 | E | C |
| ATOM | 6491 | CG | GLN | E | 272 | −4.336 | 73.901 | 36.361 | 1.00 | 29.50 | E | C |
| ATOM | 6492 | CD | GLN | E | 272 | −3.499 | 72.931 | 37.169 | 1.00 | 34.83 | E | C |
| ATOM | 6493 | OE1 | GLN | E | 272 | −2.367 | 73.241 | 37.556 | 1.00 | 38.09 | E | O |
| ATOM | 6494 | NE2 | GLN | E | 272 | −4.051 | 71.749 | 37.431 | 1.00 | 33.67 | E | N |
| ATOM | 6495 | C | GLN | E | 272 | −5.653 | 74.232 | 33.000 | 1.00 | 14.80 | E | C |
| ATOM | 6496 | O | GLN | E | 272 | −6.592 | 75.019 | 33.141 | 1.00 | 13.91 | E | O |
| ATOM | 6497 | N | VAL | E | 273 | −4.910 | 74.186 | 31.901 | 1.00 | 11.99 | E | N |
| ATOM | 6498 | CA | VAL | E | 273 | −5.185 | 75.067 | 30.777 | 1.00 | 10.54 | E | C |
| ATOM | 6499 | CB | VAL | E | 273 | −4.015 | 75.072 | 29.771 | 1.00 | 10.76 | E | C |
| ATOM | 6500 | CG1 | VAL | E | 273 | −4.368 | 75.925 | 28.569 | 1.00 | 9.98 | E | C |
| ATOM | 6501 | CG2 | VAL | E | 273 | −2.761 | 75.608 | 30.442 | 1.00 | 6.95 | E | C |
| ATOM | 6502 | C | VAL | E | 273 | −6.460 | 74.625 | 30.067 | 1.00 | 10.03 | E | C |
| ATOM | 6503 | O | VAL | E | 273 | −7.262 | 75.455 | 29.636 | 1.00 | 12.82 | E | O |
| ATOM | 6504 | N | HIS | E | 274 | −6.651 | 73.318 | 29.944 | 1.00 | 9.16 | E | N |
| ATOM | 6505 | CA | HIS | E | 274 | −7.847 | 72.802 | 29.289 | 1.00 | 12.00 | E | C |
| ATOM | 6506 | CB | HIS | E | 274 | −7.819 | 71.271 | 29.245 | 1.00 | 11.48 | E | C |
| ATOM | 6507 | CG | HIS | E | 274 | −9.145 | 70.647 | 28.919 | 1.00 | 11.33 | E | C |
| ATOM | 6508 | CD2 | HIS | E | 274 | −9.958 | 69.845 | 29.647 | 1.00 | 12.24 | E | C |
| ATOM | 6509 | ND1 | HIS | E | 274 | −9.767 | 70.811 | 27.702 | 1.00 | 14.01 | E | N |
| ATOM | 6510 | CE1 | HIS | E | 274 | −10.904 | 70.138 | 27.691 | 1.00 | 11.13 | E | C |
| ATOM | 6511 | NE2 | HIS | E | 274 | −11.043 | 69.543 | 28.862 | 1.00 | 11.49 | E | N |
| ATOM | 6512 | C | HIS | E | 274 | −9.092 | 73.266 | 30.033 | 1.00 | 14.09 | E | C |
| ATOM | 6513 | O | HIS | E | 274 | −10.028 | 73.793 | 29.431 | 1.00 | 13.41 | E | O |
| ATOM | 6514 | N | GLN | E | 275 | −9.095 | 73.073 | 31.349 | 1.00 | 17.95 | E | N |
| ATOM | 6515 | CA | GLN | E | 275 | −10.236 | 73.463 | 32.171 | 1.00 | 22.04 | E | C |
| ATOM | 6516 | CB | GLN | E | 275 | −10.058 | 72.985 | 33.611 | 1.00 | 21.81 | E | C |
| ATOM | 6517 | CG | GLN | E | 275 | −11.225 | 72.152 | 34.106 | 1.00 | 35.58 | E | C |
| ATOM | 6518 | CD | GLN | E | 275 | −11.208 | 71.961 | 35.615 | 1.00 | 44.20 | E | C |
| ATOM | 6519 | OE1 | GLN | E | 275 | −10.574 | 72.736 | 36.348 | 1.00 | 46.37 | E | O |
| ATOM | 6520 | NE2 | GLN | E | 275 | −11.906 | 70.922 | 36.091 | 1.00 | 43.34 | E | N |
| ATOM | 6521 | C | GLN | E | 275 | −10.501 | 74.958 | 32.169 | 1.00 | 19.67 | E | C |
| ATOM | 6522 | O | GLN | E | 275 | −11.650 | 75.388 | 32.128 | 1.00 | 17.43 | E | O |
| ATOM | 6523 | N | MET | E | 276 | −9.447 | 75.758 | 32.214 | 1.00 | 19.08 | E | N |
| ATOM | 6524 | CA | MET | E | 276 | −9.644 | 77.191 | 32.218 | 1.00 | 21.67 | E | C |
| ATOM | 6525 | CB | MET | E | 276 | −8.356 | 77.901 | 32.636 | 1.00 | 26.10 | E | C |
| ATOM | 6526 | CG | MET | E | 276 | −7.360 | 78.140 | 31.532 | 1.00 | 28.73 | E | C |
| ATOM | 6527 | SD | MET | E | 276 | −5.917 | 79.025 | 32.178 | 1.00 | 36.97 | E | S |
| ATOM | 6528 | CE | MET | E | 276 | −5.185 | 77.783 | 33.253 | 1.00 | 32.16 | E | C |
| ATOM | 6529 | C | MET | E | 276 | −10.117 | 77.687 | 30.859 | 1.00 | 22.91 | E | C |
| ATOM | 6530 | O | MET | E | 276 | −10.807 | 78.702 | 30.764 | 1.00 | 26.76 | E | O |
| ATOM | 6531 | N | LEU | E | 277 | −9.770 | 76.963 | 29.803 | 1.00 | 21.48 | E | N |
| ATOM | 6532 | CA | LEU | E | 277 | −10.176 | 77.361 | 28.462 | 1.00 | 17.47 | E | C |
| ATOM | 6533 | CB | LEU | E | 277 | −9.106 | 76.935 | 27.455 | 1.00 | 17.14 | E | C |
| ATOM | 6534 | CG | LEU | E | 277 | −8.152 | 77.944 | 26.803 | 1.00 | 13.95 | E | C |
| ATOM | 6535 | CD1 | LEU | E | 277 | −7.893 | 79.151 | 27.690 | 1.00 | 13.02 | E | C |
| ATOM | 6536 | CD2 | LEU | E | 277 | −6.868 | 77.222 | 26.511 | 1.00 | 12.95 | E | C |
| ATOM | 6537 | C | LEU | E | 277 | −11.516 | 76.766 | 28.026 | 1.00 | 17.35 | E | C |
| ATOM | 6538 | O | LEU | E | 277 | −12.279 | 77.415 | 27.306 | 1.00 | 17.68 | E | O |
| ATOM | 6539 | N | ASN | E | 278 | −11.820 | 75.550 | 28.486 | 1.00 | 17.24 | E | N |
| ATOM | 6540 | CA | ASN | E | 278 | −13.033 | 74.857 | 28.050 | 1.00 | 14.20 | E | C |
| ATOM | 6541 | CB | ASN | E | 278 | −12.605 | 73.671 | 27.177 | 1.00 | 14.48 | E | C |
| ATOM | 6542 | CG | ASN | E | 278 | −11.738 | 74.099 | 26.001 | 1.00 | 15.19 | E | C |
| ATOM | 6543 | OD1 | ASN | E | 278 | −10.595 | 73.647 | 25.845 | 1.00 | 12.97 | E | O |
| ATOM | 6544 | ND2 | ASN | E | 278 | −12.279 | 74.989 | 25.171 | 1.00 | 13.75 | E | N |
| ATOM | 6545 | C | ASN | E | 278 | −14.094 | 74.377 | 29.052 | 1.00 | 15.96 | E | C |
| ATOM | 6546 | O | ASN | E | 278 | −15.102 | 73.774 | 28.649 | 1.00 | 12.72 | E | O |
| ATOM | 6547 | N | GLU | E | 279 | −13.905 | 74.644 | 30.340 | 1.00 | 18.09 | E | N |
| ATOM | 6548 | CA | GLU | E | 279 | −14.877 | 74.199 | 31.339 | 1.00 | 17.32 | E | C |
| ATOM | 6549 | CB | GLU | E | 279 | −14.451 | 74.654 | 32.734 | 1.00 | 15.19 | E | C |
| ATOM | 6550 | CG | GLU | E | 279 | −14.283 | 76.149 | 32.865 | 1.00 | 19.14 | E | C |
| ATOM | 6551 | CD | GLU | E | 279 | −13.974 | 76.567 | 34.277 | 1.00 | 24.14 | E | C |
| ATOM | 6552 | OE1 | GLU | E | 279 | −14.345 | 75.816 | 35.203 | 1.00 | 28.80 | E | O |
| ATOM | 6553 | OE2 | GLU | E | 279 | −13.367 | 77.644 | 34.465 | 1.00 | 26.17 | E | O |
| ATOM | 6554 | C | GLU | E | 279 | −16.304 | 74.675 | 31.058 | 1.00 | 17.97 | E | C |
| ATOM | 6555 | O | GLU | E | 279 | −17.260 | 73.935 | 31.286 | 1.00 | 17.27 | E | O |
| ATOM | 6556 | N | MET | E | 280 | −16.453 | 75.903 | 30.568 | 1.00 | 19.39 | E | N |
| ATOM | 6557 | CA | MET | E | 280 | −17.787 | 76.429 | 30.275 | 1.00 | 21.98 | E | C |
| ATOM | 6558 | CB | MET | E | 280 | −17.709 | 77.903 | 29.873 | 1.00 | 28.61 | E | C |
| ATOM | 6559 | CG | MET | E | 280 | −17.672 | 78.900 | 31.036 | 1.00 | 37.21 | E | C |
| ATOM | 6560 | SD | MET | E | 280 | −18.396 | 78.272 | 32.591 | 1.00 | 53.17 | E | S |
| ATOM | 6561 | CE | MET | E | 280 | −19.944 | 79.206 | 32.645 | 1.00 | 46.38 | E | C |
| ATOM | 6562 | C | MET | E | 280 | −18.401 | 75.623 | 29.138 | 1.00 | 19.70 | E | C |
| ATOM | 6563 | O | MET | E | 280 | −19.607 | 75.383 | 29.096 | 1.00 | 18.51 | E | O |
| ATOM | 6564 | N | ASP | E | 281 | −17.544 | 75.195 | 28.223 | 1.00 | 19.62 | E | N |
| ATOM | 6565 | CA | ASP | E | 281 | −17.962 | 74.410 | 27.070 | 1.00 | 19.33 | E | C |
| ATOM | 6566 | CB | ASP | E | 281 | −16.824 | 74.366 | 26.051 | 1.00 | 21.49 | E | C |
| ATOM | 6567 | CG | ASP | E | 281 | −16.588 | 75.718 | 25.412 | 1.00 | 26.09 | E | C |
| ATOM | 6568 | OD1 | ASP | E | 281 | −15.461 | 76.262 | 25.517 | 1.00 | 28.17 | E | O |
| ATOM | 6569 | OD2 | ASP | E | 281 | −17.556 | 76.242 | 24.813 | 1.00 | 29.09 | E | O |
| ATOM | 6570 | C | ASP | E | 281 | −18.390 | 73.007 | 27.468 | 1.00 | 17.78 | E | C |
| ATOM | 6571 | O | ASP | E | 281 | −19.338 | 72.456 | 26.902 | 1.00 | 16.93 | E | O |
| ATOM | 6572 | N | GLU | E | 282 | −17.691 | 72.423 | 28.436 | 1.00 | 15.83 | E | N |
| ATOM | 6573 | CA | GLU | E | 282 | −18.056 | 71.094 | 28.913 | 1.00 | 13.98 | E | C |
| ATOM | 6574 | CB | GLU | E | 282 | −16.968 | 70.550 | 29.846 | 1.00 | 12.28 | E | C |
| ATOM | 6575 | CG | GLU | E | 282 | −15.695 | 70.173 | 29.114 | 1.00 | 7.97 | E | C |
| ATOM | 6576 | CD | GLU | E | 282 | −14.616 | 69.687 | 30.042 | 1.00 | 10.81 | E | C |
| ATOM | 6577 | OE1 | GLU | E | 282 | −14.538 | 70.199 | 31.175 | 1.00 | 11.36 | E | O |
| ATOM | 6578 | OE2 | GLU | E | 282 | −13.839 | 68.791 | 29.645 | 1.00 | 12.47 | E | O |
| ATOM | 6579 | C | GLU | E | 282 | −19.408 | 71.179 | 29.641 | 1.00 | 12.51 | E | C |
| ATOM | 6580 | O | GLU | E | 282 | −20.269 | 70.309 | 29.476 | 1.00 | 13.25 | E | O |
| ATOM | 6581 | N | LEU | E | 283 | −19.603 | 72.239 | 30.421 | 1.00 | 9.01 | E | N |
| ATOM | 6582 | CA | LEU | E | 283 | −20.855 | 72.439 | 31.149 | 1.00 | 11.59 | E | C |
| ATOM | 6583 | CB | LEU | E | 283 | −20.789 | 73.741 | 31.959 | 1.00 | 10.69 | E | C |
| ATOM | 6584 | CG | LEU | E | 283 | −21.405 | 73.822 | 33.359 | 1.00 | 10.22 | E | C |
| ATOM | 6585 | CD1 | LEU | E | 283 | −21.905 | 75.233 | 33.610 | 1.00 | 6.43 | E | C |
| ATOM | 6586 | CD2 | LEU | E | 283 | −22.529 | 72.817 | 33.510 | 1.00 | 5.33 | E | C |
| ATOM | 6587 | C | LEU | E | 283 | −22.036 | 72.505 | 30.175 | 1.00 | 15.45 | E | C |
| ATOM | 6588 | O | LEU | E | 283 | −23.095 | 71.891 | 30.405 | 1.00 | 17.32 | E | O |
| ATOM | 6589 | N | LYS | E | 284 | −21.852 | 73.268 | 29.098 | 1.00 | 14.57 | E | N |
| ATOM | 6590 | CA | LYS | E | 284 | −22.872 | 73.430 | 28.067 | 1.00 | 13.74 | E | C |
| ATOM | 6591 | CB | LYS | E | 284 | −22.293 | 74.240 | 26.905 | 1.00 | 17.03 | E | C |
| ATOM | 6592 | CG | LYS | E | 284 | −23.302 | 74.686 | 25.861 | 1.00 | 22.67 | E | C |
| ATOM | 6593 | CD | LYS | E | 284 | −22.619 | 75.405 | 24.706 | 1.00 | 25.17 | E | C |
| ATOM | 6594 | CE | LYS | E | 284 | −23.619 | 75.848 | 23.646 | 1.00 | 28.10 | E | C |
| ATOM | 6595 | NZ | LYS | E | 284 | −23.108 | 76.999 | 22.841 | 1.00 | 33.22 | E | N |
| ATOM | 6596 | C | LYS | E | 284 | −23.371 | 72.070 | 27.567 | 1.00 | 14.05 | E | C |
| ATOM | 6597 | O | LYS | E | 284 | −24.575 | 71.853 | 27.403 | 1.00 | 12.83 | E | O |
| ATOM | 6598 | N | GLU | E | 285 | −22.448 | 71.146 | 27.332 | 1.00 | 12.49 | E | N |
| ATOM | 6599 | CA | GLU | E | 285 | −22.834 | 69.821 | 26.862 | 1.00 | 14.89 | E | C |
| ATOM | 6600 | CB | GLU | E | 285 | −21.602 | 68.922 | 26.718 | 1.00 | 14.11 | E | C |
| ATOM | 6601 | CG | GLU | E | 285 | −20.677 | 69.236 | 25.559 | 1.00 | 13.94 | E | C |
| ATOM | 6602 | CD | GLU | E | 285 | −19.816 | 68.035 | 25.178 | 1.00 | 16.27 | E | C |
| ATOM | 6603 | OE1 | GLU | E | 285 | −20.380 | 67.016 | 24.712 | 1.00 | 18.86 | E | O |
| ATOM | 6604 | OE2 | GLU | E | 285 | −18.581 | 68.100 | 25.349 | 1.00 | 15.14 | E | O |
| ATOM | 6605 | C | GLU | E | 285 | −23.799 | 69.173 | 27.860 | 1.00 | 16.85 | E | C |
| ATOM | 6606 | O | GLU | E | 285 | −24.842 | 68.637 | 27.474 | 1.00 | 18.01 | E | O |
| ATOM | 6607 | N | LEU | E | 286 | −23.447 | 69.230 | 29.146 | 1.00 | 17.11 | E | N |
| ATOM | 6608 | CA | LEU | E | 286 | −24.261 | 68.620 | 30.195 | 1.00 | 15.86 | E | C |
| ATOM | 6609 | CB | LEU | E | 286 | −23.530 | 68.662 | 31.542 | 1.00 | 15.67 | E | C |
| ATOM | 6610 | CG | LEU | E | 286 | −22.107 | 68.103 | 31.719 | 1.00 | 17.26 | E | C |
| ATOM | 6611 | CD1 | LEU | E | 286 | −22.028 | 67.399 | 33.061 | 1.00 | 16.34 | E | C |
| ATOM | 6612 | CD2 | LEU | E | 286 | −21.732 | 67.151 | 30.613 | 1.00 | 13.05 | E | C |
| ATOM | 6613 | C | LEU | E | 286 | −25.611 | 69.295 | 30.338 | 1.00 | 16.71 | E | C |
| ATOM | 6614 | O | LEU | E | 286 | −26.623 | 68.629 | 30.557 | 1.00 | 18.13 | E | O |
| ATOM | 6615 | N | LYS | E | 287 | −25.627 | 70.619 | 30.233 | 1.00 | 18.11 | E | N |
| ATOM | 6616 | CA | LYS | E | 287 | −26.878 | 71.363 | 30.342 | 1.00 | 19.53 | E | C |
| ATOM | 6617 | CB | LYS | E | 287 | −26.605 | 72.865 | 30.324 | 1.00 | 18.96 | E | C |
| ATOM | 6618 | CG | LYS | E | 287 | −26.306 | 73.464 | 31.678 | 1.00 | 20.58 | E | C |
| ATOM | 6619 | CD | LYS | E | 287 | −25.360 | 74.641 | 31.540 | 1.00 | 23.21 | E | C |
| ATOM | 6620 | CE | LYS | E | 287 | −26.016 | 75.938 | 31.971 | 1.00 | 25.88 | E | C |
| ATOM | 6621 | NZ | LYS | E | 287 | −25.004 | 77.016 | 32.170 | 1.00 | 29.13 | E | N |
| ATOM | 6622 | C | LYS | E | 287 | −27.825 | 71.008 | 29.196 | 1.00 | 20.58 | E | C |
| ATOM | 6623 | O | LYS | E | 287 | −29.038 | 70.966 | 29.377 | 1.00 | 21.88 | E | O |
| ATOM | 6624 | N | ASN | E | 288 | −27.270 | 70.753 | 28.015 | 1.00 | 21.62 | E | N |
| ATOM | 6625 | CA | ASN | E | 288 | −28.090 | 70.407 | 26.855 | 1.00 | 23.51 | E | C |
| ATOM | 6626 | CB | ASN | E | 288 | −27.424 | 70.880 | 25.558 | 1.00 | 24.93 | E | C |
| ATOM | 6627 | CG | ASN | E | 288 | −27.371 | 72.394 | 25.444 | 1.00 | 24.17 | E | C |
| ATOM | 6628 | OD1 | ASN | E | 288 | −28.315 | 73.092 | 25.808 | 1.00 | 20.53 | E | O |
| ATOM | 6629 | ND2 | ASN | E | 288 | −26.258 | 72.905 | 24.936 | 1.00 | 26.77 | E | N |
| ATOM | 6630 | C | ASN | E | 288 | −28.368 | 68.914 | 26.762 | 1.00 | 23.02 | E | C |
| ATOM | 6631 | O | ASN | E | 288 | −28.809 | 68.419 | 25.728 | 1.00 | 24.06 | E | O |
| ATOM | 6632 | N | ASN | E | 289 | −28.097 | 68.199 | 27.846 | 1.00 | 24.60 | E | N |
| ATOM | 6633 | CA | ASN | E | 289 | −28.348 | 66.763 | 27.913 | 1.00 | 24.79 | E | C |
| ATOM | 6634 | CB | ASN | E | 289 | −27.106 | 66.050 | 28.450 | 1.00 | 22.66 | E | C |
| ATOM | 6635 | CG | ASN | E | 289 | −27.238 | 64.546 | 28.428 | 1.00 | 20.20 | E | C |
| ATOM | 6636 | OD1 | ASN | E | 289 | −27.901 | 63.977 | 27.566 | 1.00 | 21.09 | E | O |
| ATOM | 6637 | ND2 | ASN | E | 289 | −26.596 | 63.893 | 29.381 | 1.00 | 21.38 | E | N |
| ATOM | 6638 | C | ASN | E | 289 | −29.525 | 66.625 | 28.880 | 1.00 | 28.16 | E | C |
| ATOM | 6639 | O | ASN | E | 289 | −29.336 | 66.516 | 30.094 | 1.00 | 32.56 | E | O |
| ATOM | 6640 | N | PRO | E | 290 | −30.761 | 66.648 | 28.350 | 1.00 | 28.80 | E | N |
| ATOM | 6641 | CD | PRO | E | 290 | −31.064 | 66.768 | 26.914 | 1.00 | 25.26 | E | C |
| ATOM | 6642 | CA | PRO | E | 290 | −31.986 | 66.539 | 29.154 | 1.00 | 29.87 | E | C |
| ATOM | 6643 | CB | PRO | E | 290 | −33.083 | 66.966 | 28.186 | 1.00 | 28.40 | E | C |
| ATOM | 6644 | CG | PRO | E | 290 | −32.551 | 66.576 | 26.858 | 1.00 | 27.94 | E | C |
| ATOM | 6645 | C | PRO | E | 290 | −32.255 | 65.164 | 29.738 | 1.00 | 31.96 | E | C |
| ATOM | 6646 | O | PRO | E | 290 | −33.149 | 64.991 | 30.564 | 1.00 | 31.76 | E | O |
| ATOM | 6647 | N | HIS | E | 291 | −31.476 | 64.184 | 29.313 | 1.00 | 33.70 | E | N |
| ATOM | 6648 | CA | HIS | E | 291 | −31.663 | 62.829 | 29.804 | 1.00 | 37.84 | E | C |
| ATOM | 6649 | CB | HIS | E | 291 | −31.065 | 61.823 | 28.813 | 1.00 | 40.71 | E | C |
| ATOM | 6650 | CG | HIS | E | 291 | −31.541 | 62.005 | 27.405 | 1.00 | 48.17 | E | C |
| ATOM | 6651 | CD2 | HIS | E | 291 | −32.510 | 61.371 | 26.704 | 1.00 | 47.61 | E | C |
| ATOM | 6652 | ND1 | HIS | E | 291 | −31.002 | 62.945 | 26.552 | 1.00 | 50.57 | E | N |
| ATOM | 6653 | CE1 | HIS | E | 291 | −31.619 | 62.881 | 25.385 | 1.00 | 49.18 | E | C |
| ATOM | 6654 | NE2 | HIS | E | 291 | −32.538 | 61.934 | 25.451 | 1.00 | 48.49 | E | N |
| ATOM | 6655 | C | HIS | E | 291 | −31.043 | 62.594 | 31.179 | 1.00 | 37.85 | E | C |
| ATOM | 6656 | O | HIS | E | 291 | −31.493 | 61.726 | 31.926 | 1.00 | 40.07 | E | O |
| ATOM | 6657 | N | ARG | E | 292 | −30.033 | 63.378 | 31.534 | 1.00 | 32.70 | E | N |
| ATOM | 6658 | CA | ARG | E | 292 | −29.363 | 63.137 | 32.791 | 1.00 | 26.91 | E | C |
| ATOM | 6659 | CB | ARG | E | 292 | −28.304 | 62.062 | 32.556 | 1.00 | 24.65 | E | C |
| ATOM | 6660 | CG | ARG | E | 292 | −28.607 | 60.740 | 33.205 | 1.00 | 26.95 | E | C |
| ATOM | 6661 | CD | ARG | E | 292 | −28.060 | 59.604 | 32.396 | 1.00 | 23.84 | E | C |
| ATOM | 6662 | NE | ARG | E | 292 | −29.128 | 58.879 | 31.721 | 1.00 | 25.88 | E | N |
| ATOM | 6663 | CZ | ARG | E | 292 | −29.962 | 58.041 | 32.323 | 1.00 | 23.00 | E | C |
| ATOM | 6664 | NH1 | ARG | E | 292 | −29.865 | 57.810 | 33.622 | 1.00 | 28.74 | E | N |
| ATOM | 6665 | NH2 | ARG | E | 292 | −30.889 | 57.419 | 31.619 | 1.00 | 26.47 | E | N |
| ATOM | 6666 | C | ARG | E | 292 | −28.695 | 64.308 | 33.494 | 1.00 | 26.37 | E | C |
| ATOM | 6667 | O | ARG | E | 292 | −28.451 | 65.379 | 32.906 | 1.00 | 26.39 | E | O |
| ATOM | 6668 | N | ASP | E | 293 | −28.409 | 64.062 | 34.772 | 1.00 | 22.25 | E | N |
| ATOM | 6669 | CA | ASP | E | 293 | −27.680 | 64.973 | 35.650 | 1.00 | 21.24 | E | C |
| ATOM | 6670 | CB | ASP | E | 293 | −28.603 | 65.965 | 36.387 | 1.00 | 19.70 | E | C |
| ATOM | 6671 | CG | ASP | E | 293 | −29.610 | 65.294 | 37.293 | 1.00 | 23.74 | E | C |
| ATOM | 6672 | OD1 | ASP | E | 293 | −30.707 | 65.878 | 37.461 | 1.00 | 24.26 | E | O |
| ATOM | 6673 | OD2 | ASP | E | 293 | −29.317 | 64.210 | 37.845 | 1.00 | 20.02 | E | O |
| ATOM | 6674 | C | ASP | E | 293 | −26.940 | 64.041 | 36.609 | 1.00 | 19.13 | E | C |
| ATOM | 6675 | O | ASP | E | 293 | −27.140 | 62.830 | 36.556 | 1.00 | 16.83 | E | O |
| ATOM | 6676 | N | ASP | E | 294 | −26.075 | 64.572 | 37.461 | 1.00 | 19.42 | E | N |
| ATOM | 6677 | CA | PHE | E | 294 | −25.327 | 63.707 | 38.366 | 1.00 | 20.28 | E | C |
| ATOM | 6678 | CB | PHE | E | 294 | −24.487 | 64.540 | 39.343 | 1.00 | 20.35 | E | C |
| ATOM | 6679 | CG | PHE | E | 294 | −23.724 | 63.706 | 40.346 | 1.00 | 20.75 | E | C |
| ATOM | 6680 | CD1 | PHE | E | 294 | −22.558 | 63.045 | 39.978 | 1.00 | 19.18 | E | C |
| ATOM | 6681 | CD2 | PHE | E | 294 | −24.185 | 63.564 | 41.651 | 1.00 | 20.11 | E | C |
| ATOM | 6682 | CE1 | PHE | E | 294 | −21.863 | 62.253 | 40.892 | 1.00 | 18.18 | E | C |
| ATOM | 6683 | CE2 | PHE | E | 294 | −23.492 | 62.772 | 42.568 | 1.00 | 18.75 | E | C |
| ATOM | 6684 | CZ | PHE | E | 294 | −22.332 | 62.118 | 42.186 | 1.00 | 16.36 | E | C |
| ATOM | 6685 | C | PHE | E | 294 | −26.188 | 62.737 | 39.169 | 1.00 | 18.83 | E | C |
| ATOM | 6686 | O | PHE | E | 294 | −25.793 | 61.602 | 39.412 | 1.00 | 18.97 | E | O |
| ATOM | 6687 | N | TYR | E | 295 | −27.372 | 63.179 | 39.567 | 1.00 | 19.15 | E | N |
| ATOM | 6688 | CA | TYR | E | 295 | −28.241 | 62.359 | 40.389 | 1.00 | 18.28 | E | C |
| ATOM | 6689 | CB | TYR | E | 295 | −29.318 | 63.242 | 41.015 | 1.00 | 18.41 | E | C |
| ATOM | 6690 | CG | TYR | E | 295 | −28.697 | 64.273 | 41.926 | 1.00 | 21.18 | E | C |
| ATOM | 6691 | CD1 | TYR | E | 295 | −28.268 | 63.927 | 43.206 | 1.00 | 22.34 | E | C |
| ATOM | 6692 | CE1 | TYR | E | 295 | −27.626 | 64.848 | 44.026 | 1.00 | 21.49 | E | C |
| ATOM | 6693 | CD2 | TYR | E | 295 | −28.467 | 65.574 | 41.488 | 1.00 | 20.90 | E | C |
| ATOM | 6694 | CE2 | TYR | E | 295 | −27.824 | 66.504 | 42.301 | 1.00 | 22.05 | E | C |
| ATOM | 6695 | CZ | TYR | E | 295 | −27.408 | 66.132 | 43.568 | 1.00 | 23.73 | E | C |
| ATOM | 6696 | OH | TYR | E | 295 | −26.800 | 67.052 | 44.391 | 1.00 | 29.19 | E | O |
| ATOM | 6697 | C | TYR | E | 295 | −28.849 | 61.110 | 39.779 | 1.00 | 20.42 | E | C |
| ATOM | 6698 | O | TYR | E | 295 | −29.288 | 60.221 | 40.511 | 1.00 | 22.40 | E | O |
| ATOM | 6699 | N | ASN | E | 296 | −28.903 | 61.009 | 38.459 | 1.00 | 18.64 | E | N |
| ATOM | 6700 | CA | ASN | E | 296 | −29.443 | 59.777 | 37.904 | 1.00 | 16.68 | E | C |
| ATOM | 6701 | CB | ASN | E | 296 | −30.820 | 59.984 | 37.243 | 1.00 | 17.26 | E | C |
| ATOM | 6702 | CG | ASN | E | 296 | −30.781 | 60.837 | 36.004 | 1.00 | 17.24 | E | C |
| ATOM | 6703 | OD1 | ASN | E | 296 | −31.767 | 60.901 | 35.281 | 1.00 | 15.17 | E | O |
| ATOM | 6704 | ND2 | ASN | E | 296 | −29.662 | 61.503 | 35.751 | 1.00 | 18.84 | E | N |
| ATOM | 6705 | C | ASN | E | 296 | −28.461 | 59.067 | 36.994 | 1.00 | 16.40 | E | C |
| ATOM | 6706 | O | ASN | E | 296 | −28.841 | 58.405 | 36.037 | 1.00 | 16.10 | E | O |
| ATOM | 6707 | N | CYS | E | 297 | −27.182 | 59.221 | 37.341 | 1.00 | 18.06 | E | N |
| ATOM | 6708 | CA | CYS | E | 297 | −26.052 | 58.569 | 36.683 | 1.00 | 14.55 | E | C |
| ATOM | 6709 | CB | CYS | E | 297 | −24.817 | 59.471 | 36.666 | 1.00 | 15.75 | E | C |
| ATOM | 6710 | SG | CYS | E | 297 | −24.749 | 60.654 | 35.337 | 1.00 | 24.16 | E | S |
| ATOM | 6711 | C | CYS | E | 297 | −25.774 | 57.441 | 37.667 | 1.00 | 15.16 | E | C |
| ATOM | 6712 | O | CYS | E | 297 | −26.001 | 57.601 | 38.868 | 1.00 | 13.20 | E | O |
| ATOM | 6713 | N | ARG | E | 298 | −25.287 | 56.307 | 37.190 | 1.00 | 14.95 | E | N |
| ATOM | 6714 | CA | ARG | E | 298 | −24.997 | 55.219 | 38.106 | 1.00 | 15.88 | E | C |
| ATOM | 6715 | CB | ARG | E | 298 | −24.974 | 53.891 | 37.362 | 1.00 | 16.11 | E | C |
| ATOM | 6716 | CG | ARG | E | 298 | −26.302 | 53.166 | 37.383 | 1.00 | 17.74 | E | C |
| ATOM | 6717 | CD | ARG | E | 298 | −27.334 | 53.894 | 36.547 | 1.00 | 16.86 | E | C |
| ATOM | 6718 | NE | ARG | E | 298 | −28.609 | 53.184 | 36.539 | 1.00 | 21.62 | E | N |
| ATOM | 6719 | CZ | ARG | E | 298 | −29.597 | 53.441 | 35.690 | 1.00 | 21.38 | E | C |
| ATOM | 6720 | NH1 | ARG | E | 298 | −29.451 | 54.394 | 34.777 | 1.00 | 23.74 | E | N |
| ATOM | 6721 | NH2 | ARG | E | 298 | −30.730 | 52.754 | 35.757 | 1.00 | 17.93 | E | N |
| ATOM | 6722 | C | ARG | E | 298 | −23.651 | 55.459 | 38.774 | 1.00 | 20.28 | E | C |
| ATOM | 6723 | O | ARG | E | 298 | −22.693 | 55.884 | 38.122 | 1.00 | 20.76 | E | O |
| ATOM | 6724 | N | LYS | E | 299 | −23.589 | 55.206 | 40.080 | 1.00 | 20.45 | E | N |
| ATOM | 6725 | CA | LYS | E | 299 | −22.356 | 55.370 | 40.849 | 1.00 | 18.50 | E | C |
| ATOM | 6726 | CB | LYS | E | 299 | −22.530 | 56.463 | 41.901 | 1.00 | 15.85 | E | C |
| ATOM | 6727 | CG | LYS | E | 299 | −21.964 | 57.809 | 41.501 | 1.00 | 17.36 | E | C |
| ATOM | 6728 | CD | LYS | E | 299 | −23.036 | 58.753 | 40.970 | 1.00 | 17.06 | E | C |
| ATOM | 6729 | CE | LYS | E | 299 | −24.344 | 58.602 | 41.719 | 1.00 | 16.12 | E | C |
| ATOM | 6730 | NZ | LYS | E | 299 | −25.453 | 59.320 | 41.048 | 1.00 | 13.93 | E | N |
| ATOM | 6731 | C | LYS | E | 299 | −22.092 | 54.040 | 41.537 | 1.00 | 16.47 | E | C |
| ATOM | 6732 | O | LYS | E | 299 | −23.005 | 53.454 | 42.108 | 1.00 | 18.60 | E | O |
| ATOM | 6733 | N | VAL | E | 300 | −20.858 | 53.554 | 41.484 | 1.00 | 13.59 | E | N |
| ATOM | 6734 | CA | VAL | E | 300 | −20.541 | 52.282 | 42.123 | 1.00 | 14.28 | E | C |
| ATOM | 6735 | CB | VAL | E | 300 | −20.066 | 51.256 | 41.080 | 1.00 | 12.98 | E | C |
| ATOM | 6736 | CG1 | VAL | E | 300 | −19.862 | 49.908 | 41.728 | 1.00 | 9.48 | E | C |
| ATOM | 6737 | CG2 | VAL | E | 300 | −21.090 | 51.150 | 39.963 | 1.00 | 12.83 | E | C |
| ATOM | 6738 | C | VAL | E | 300 | −19.479 | 52.392 | 43.223 | 1.00 | 15.10 | E | C |
| ATOM | 6739 | O | VAL | E | 300 | −18.437 | 53.023 | 43.032 | 1.00 | 19.70 | E | O |
| ATOM | 6740 | N | ASP | E | 301 | −19.759 | 51.794 | 44.378 | 1.00 | 14.85 | E | N |
| ATOM | 6741 | CA | ASP | E | 301 | −18.820 | 51.792 | 45.498 | 1.00 | 13.01 | E | C |
| ATOM | 6742 | CB | ASP | E | 301 | −19.547 | 51.545 | 46.824 | 1.00 | 13.98 | E | C |
| ATOM | 6743 | CG | ASP | E | 301 | −18.735 | 51.988 | 48.030 | 1.00 | 14.74 | E | C |
| ATOM | 6744 | OD1 | ASP | E | 301 | −19.324 | 52.149 | 49.115 | 1.00 | 20.53 | E | O |
| ATOM | 6745 | OD2 | ASP | E | 301 | −17.510 | 52.177 | 47.903 | 1.00 | 16.17 | E | O |
| ATOM | 6746 | C | ASP | E | 301 | −17.898 | 50.633 | 45.193 | 1.00 | 11.93 | E | C |
| ATOM | 6747 | O | ASP | E | 301 | −18.170 | 49.482 | 45.534 | 1.00 | 8.32 | E | O |
| ATOM | 6748 | N | THR | E | 302 | −16.796 | 50.952 | 44.544 | 1.00 | 12.10 | E | N |
| ATOM | 6749 | CA | THR | E | 302 | −15.842 | 49.948 | 44.122 | 1.00 | 15.53 | E | C |
| ATOM | 6750 | CB | THR | E | 302 | −14.972 | 50.534 | 42.992 | 1.00 | 15.84 | E | C |
| ATOM | 6751 | OG1 | THR | E | 302 | −14.648 | 51.897 | 43.300 | 1.00 | 11.41 | E | O |
| ATOM | 6752 | CG2 | THR | E | 302 | −15.740 | 50.495 | 41.664 | 1.00 | 8.35 | E | C |
| ATOM | 6753 | C | THR | E | 302 | −14.941 | 49.359 | 45.202 | 1.00 | 16.66 | E | C |
| ATOM | 6754 | O | THR | E | 302 | −14.186 | 48.419 | 44.943 | 1.00 | 16.49 | E | O |
| ATOM | 6755 | N | HIS | E | 303 | −15.026 | 49.885 | 46.416 | 1.00 | 16.71 | E | N |
| ATOM | 6756 | CA | HIS | E | 303 | −14.165 | 49.401 | 47.484 | 1.00 | 17.30 | E | C |
| ATOM | 6757 | CB | HIS | E | 303 | −12.871 | 50.207 | 47.483 | 1.00 | 18.61 | E | C |
| ATOM | 6758 | CG | HIS | E | 303 | −12.073 | 50.087 | 48.741 | 1.00 | 21.60 | E | C |
| ATOM | 6759 | CD2 | HIS | E | 303 | −11.788 | 49.017 | 49.522 | 1.00 | 18.20 | E | C |
| ATOM | 6760 | ND1 | HIS | E | 303 | −11.417 | 51.162 | 49.305 | 1.00 | 19.88 | E | N |
| ATOM | 6761 | CE1 | HIS | E | 303 | −10.762 | 50.758 | 50.378 | 1.00 | 21.15 | E | C |
| ATOM | 6762 | NE2 | HIS | E | 303 | −10.971 | 49.463 | 50.531 | 1.00 | 21.96 | E | N |
| ATOM | 6763 | C | HIS | E | 303 | −14.873 | 49.533 | 48.814 | 1.00 | 19.04 | E | C |
| ATOM | 6764 | O | HIS | E | 303 | −14.827 | 50.596 | 49.445 | 1.00 | 16.91 | E | O |
| ATOM | 6765 | N | ILE | E | 304 | −15.514 | 48.441 | 49.234 | 1.00 | 18.12 | E | N |
| ATOM | 6766 | CA | ILE | E | 304 | −16.269 | 48.415 | 50.474 | 1.00 | 17.33 | E | C |
| ATOM | 6767 | CB | ILE | E | 304 | −17.725 | 48.858 | 50.208 | 1.00 | 16.62 | E | C |
| ATOM | 6768 | CG2 | ILE | E | 304 | −18.275 | 48.111 | 49.018 | 1.00 | 14.76 | E | C |
| ATOM | 6769 | CG1 | ILE | E | 304 | −18.598 | 48.622 | 51.438 | 1.00 | 16.07 | E | C |
| ATOM | 6770 | CD1 | ILE | E | 304 | −19.761 | 49.600 | 51.535 | 1.00 | 13.12 | E | C |
| ATOM | 6771 | C | ILE | E | 304 | −16.257 | 47.020 | 51.094 | 1.00 | 17.46 | E | C |
| ATOM | 6772 | O | ILE | E | 304 | −16.435 | 46.022 | 50.394 | 1.00 | 18.05 | E | O |
| ATOM | 6773 | N | HIS | E | 305 | −16.048 | 46.959 | 52.410 | 1.00 | 15.35 | E | N |
| ATOM | 6774 | CA | HIS | E | 305 | −16.011 | 45.689 | 53.130 | 1.00 | 12.12 | E | C |
| ATOM | 6775 | CD | HIS | E | 305 | −14.926 | 45.739 | 54.202 | 1.00 | 11.13 | E | C |
| ATOM | 6776 | CG | HIS | E | 305 | −13.577 | 46.117 | 53.674 | 1.00 | 10.33 | E | C |
| ATOM | 6777 | CD2 | HIS | E | 305 | −13.033 | 47.332 | 53.397 | 1.00 | 10.43 | E | C |
| ATOM | 6778 | ND1 | HIS | E | 305 | −12.602 | 45.187 | 53.381 | 1.00 | 9.49 | E | N |
| ATOM | 6779 | CE1 | HIS | E | 305 | −11.519 | 45.809 | 52.947 | 1.00 | 12.03 | E | C |
| ATOM | 6780 | NE2 | HIS | E | 305 | −11.756 | 47.110 | 52.947 | 1.00 | 8.93 | E | N |
| ATOM | 6781 | C | HIS | E | 305 | −17.369 | 45.387 | 53.755 | 1.00 | 10.78 | E | C |
| ATOM | 6782 | O | HIS | E | 305 | −17.927 | 46.210 | 54.468 | 1.00 | 13.76 | E | O |
| ATOM | 6783 | N | ALA | E | 306 | −17.892 | 44.197 | 53.475 | 1.00 | 11.29 | E | N |
| ATOM | 6784 | CA | ALA | E | 306 | −19.201 | 43.769 | 53.969 | 1.00 | 12.68 | E | C |
| ATOM | 6785 | CB | ALA | E | 306 | −19.428 | 42.298 | 53.630 | 1.00 | 6.07 | E | C |
| ATOM | 6786 | C | ALA | E | 306 | −19.424 | 43.998 | 55.463 | 1.00 | 15.15 | E | C |
| ATOM | 6787 | O | ALA | E | 306 | −20.486 | 44.474 | 55.867 | 1.00 | 17.04 | E | O |
| ATOM | 6788 | N | ALA | E | 307 | −18.427 | 43.665 | 56.277 | 1.00 | 15.57 | E | N |
| ATOM | 6789 | CA | ALA | E | 307 | −18.528 | 43.828 | 57.720 | 1.00 | 16.04 | E | C |
| ATOM | 6790 | CB | ALA | E | 307 | −17.269 | 43.299 | 58.381 | 1.00 | 11.22 | E | C |
| ATOM | 6791 | C | ALA | E | 307 | −18.775 | 45.269 | 58.160 | 1.00 | 16.14 | E | C |
| ATOM | 6792 | O | ALA | E | 307 | −19.111 | 45.509 | 59.314 | 1.00 | 20.76 | E | O |
| ATOM | 6793 | N | ALA | E | 308 | −18.619 | 46.224 | 57.252 | 1.00 | 12.45 | E | N |
| ATOM | 6794 | CA | ALA | E | 308 | −18.815 | 47.620 | 57.600 | 1.00 | 11.25 | E | C |
| ATOM | 6795 | CB | ALA | E | 308 | −17.477 | 48.302 | 57.720 | 1.00 | 11.66 | E | C |
| ATOM | 6796 | C | ALA | E | 308 | −19.678 | 48.363 | 56.600 | 1.00 | 14.62 | E | C |
| ATOM | 6797 | O | ALA | E | 308 | −19.688 | 49.597 | 56.576 | 1.00 | 13.99 | E | O |
| ATOM | 6798 | N | CYS | E | 309 | −20.427 | 47.621 | 55.793 | 1.00 | 17.06 | E | N |
| ATOM | 6799 | CA | CYS | E | 309 | −21.265 | 48.238 | 54.770 | 1.00 | 19.34 | E | C |
| ATOM | 6800 | CB | CYS | E | 309 | −21.649 | 47.206 | 53.702 | 1.00 | 20.94 | E | C |
| ATOM | 6801 | SG | CYS | E | 309 | −22.746 | 45.872 | 54.236 | 1.00 | 20.44 | E | S |
| ATOM | 6802 | C | CYS | E | 309 | −22.518 | 48.936 | 55.277 | 1.00 | 20.56 | E | C |
| ATOM | 6803 | O | CYS | E | 309 | −23.212 | 49.603 | 54.505 | 1.00 | 22.34 | E | O |
| ATOM | 6804 | N | MET | E | 310 | −22.811 | 48.802 | 56.567 | 1.00 | 20.40 | E | N |
| ATOM | 6805 | CA | MET | E | 310 | −24.002 | 49.445 | 57.133 | 1.00 | 18.15 | E | C |
| ATOM | 6806 | CB | MET | E | 310 | −24.778 | 48.444 | 58.001 | 1.00 | 16.16 | E | C |
| ATOM | 6807 | CG | MET | E | 310 | −24.186 | 48.205 | 59.383 | 1.00 | 10.44 | E | C |
| ATOM | 6808 | SD | MET | E | 310 | −22.566 | 47.412 | 59.336 | 1.00 | 13.83 | E | S |
| ATOM | 6809 | CE | MET | E | 310 | −22.974 | 45.777 | 58.764 | 1.00 | 8.85 | E | C |
| ATOM | 6810 | C | MET | E | 310 | −23.638 | 50.684 | 57.958 | 1.00 | 19.82 | E | C |
| ATOM | 6811 | O | MET | E | 310 | −22.514 | 50.808 | 58.450 | 1.00 | 18.10 | E | O |
| ATOM | 6812 | N | ASN | E | 311 | −24.579 | 51.614 | 58.091 | 1.00 | 21.22 | E | N |
| ATOM | 6813 | CA | ASN | E | 311 | −24.312 | 52.806 | 58.885 | 1.00 | 24.94 | E | C |
| ATOM | 6814 | CB | ASN | E | 311 | −25.359 | 53.906 | 58.649 | 1.00 | 30.29 | E | C |
| ATOM | 6815 | CG | ASN | E | 311 | −24.998 | 55.216 | 59.374 | 1.00 | 41.35 | E | C |
| ATOM | 6816 | OD1 | ASN | E | 311 | −23.876 | 55.735 | 59.231 | 1.00 | 45.68 | E | O |
| ATOM | 6817 | ND2 | ASN | E | 311 | −25.940 | 55.749 | 60.162 | 1.00 | 41.90 | E | N |
| ATOM | 6818 | C | ASN | E | 311 | −24.339 | 52.399 | 60.350 | 1.00 | 21.77 | E | C |
| ATOM | 6819 | O | ASN | E | 311 | −25.012 | 51.438 | 60.726 | 1.00 | 19.77 | E | O |
| ATOM | 6820 | N | GLN | E | 312 | −23.604 | 53.128 | 61.177 | 1.00 | 20.74 | E | N |
| ATOM | 6821 | CA | GLN | E | 312 | −23.568 | 52.813 | 62.590 | 1.00 | 20.42 | E | C |
| ATOM | 6822 | CB | GLN | E | 312 | −22.569 | 53.718 | 63.297 | 1.00 | 17.19 | E | C |
| ATOM | 6823 | CG | GLN | E | 312 | −22.934 | 55.170 | 63.298 | 1.00 | 16.13 | E | C |
| ATOM | 6824 | CD | GLN | E | 312 | −21.956 | 55.989 | 64.116 | 1.00 | 19.45 | E | C |
| ATOM | 6825 | OE1 | GLN | E | 312 | −21.259 | 55.460 | 64.987 | 1.00 | 20.02 | E | O |
| ATOM | 6826 | NE2 | GLN | E | 312 | −21.892 | 57.287 | 63.839 | 1.00 | 19.49 | E | N |
| ATOM | 6827 | C | GLN | E | 312 | −24.955 | 52.941 | 63.222 | 1.00 | 20.80 | E | C |
| ATOM | 6828 | O | GLN | E | 312 | −25.278 | 52.215 | 64.158 | 1.00 | 24.12 | E | O |
| ATOM | 6829 | N | LYS | E | 313 | −25.778 | 53.851 | 62.706 | 1.00 | 19.43 | E | N |
| ATOM | 6830 | CA | LYS | E | 313 | −27.125 | 54.035 | 63.231 | 1.00 | 18.23 | E | C |
| ATOM | 6831 | CB | LYS | E | 313 | −27.703 | 55.369 | 62.762 | 1.00 | 18.10 | E | C |
| ATOM | 6832 | CG | LYS | E | 313 | −27.785 | 56.406 | 63.871 | 1.00 | 24.78 | E | C |
| ATOM | 6833 | CD | LYS | E | 313 | −28.671 | 57.567 | 63.482 | 1.00 | 31.69 | E | C |
| ATOM | 6834 | CE | LYS | E | 313 | −28.031 | 58.378 | 62.361 | 1.00 | 37.23 | E | C |
| ATOM | 6835 | NZ | LYS | E | 313 | −28.857 | 58.337 | 61.107 | 1.00 | 42.74 | E | N |
| ATOM | 6836 | C | LYS | E | 313 | −28.031 | 52.895 | 62.788 | 1.00 | 19.02 | E | C |
| ATOM | 6837 | O | LYS | E | 313 | −29.057 | 52.610 | 63.417 | 1.00 | 19.38 | E | O |
| ATOM | 6838 | N | HIS | E | 314 | −27.640 | 52.247 | 61.696 | 1.00 | 19.34 | E | N |
| ATOM | 6839 | CA | HIS | E | 314 | −28.385 | 51.126 | 61.153 | 1.00 | 17.45 | E | C |
| ATOM | 6840 | CB | HIS | E | 314 | −27.962 | 50.885 | 59.698 | 1.00 | 18.60 | E | C |
| ATOM | 6841 | CG | HIS | E | 314 | −28.661 | 49.738 | 59.034 | 1.00 | 21.43 | E | C |
| ATOM | 6842 | CD2 | HIS | E | 314 | −28.538 | 49.223 | 57.789 | 1.00 | 22.79 | E | C |
| ATOM | 6843 | ND1 | HIS | E | 314 | −29.597 | 48.955 | 59.678 | 1.00 | 26.66 | E | N |
| ATOM | 6844 | CE1 | HIS | E | 314 | −30.016 | 48.007 | 58.860 | 1.00 | 25.48 | E | C |
| ATOM | 6845 | NE2 | HIS | E | 314 | −29.389 | 48.147 | 57.705 | 1.00 | 25.60 | E | N |
| ATOM | 6846 | C | HIS | E | 314 | −28.070 | 49.910 | 62.025 | 1.00 | 17.15 | E | C |
| ATOM | 6847 | O | HIS | E | 314 | −28.957 | 49.130 | 62.368 | 1.00 | 16.26 | E | O |
| ATOM | 6848 | N | LEU | E | 315 | −26.803 | 49.756 | 62.392 | 1.00 | 17.42 | E | N |
| ATOM | 6849 | CA | LEU | E | 315 | −26.404 | 48.639 | 63.230 | 1.00 | 17.98 | E | C |
| ATOM | 6850 | CB | LEU | E | 315 | −24.883 | 48.602 | 63.382 | 1.00 | 16.91 | E | C |
| ATOM | 6851 | CG | LEU | E | 315 | −24.360 | 47.583 | 64.400 | 1.00 | 17.22 | E | C |
| ATOM | 6852 | CD1 | LEU | E | 315 | −24.737 | 46.171 | 63.960 | 1.00 | 12.12 | E | C |
| ATOM | 6853 | CD2 | LEU | E | 315 | −22.847 | 47.728 | 64.545 | 1.00 | 15.53 | E | C |
| ATOM | 6854 | C | LEU | E | 315 | −27.061 | 48.782 | 64.601 | 1.00 | 20.06 | E | C |
| ATOM | 6855 | O | LEU | E | 315 | −27.617 | 47.823 | 65.130 | 1.00 | 23.19 | E | O |
| ATOM | 6856 | N | LEU | E | 316 | −27.004 | 49.983 | 65.169 | 1.00 | 18.49 | E | N |
| ATOM | 6857 | CA | LEU | E | 316 | −27.599 | 50.244 | 66.477 | 1.00 | 17.73 | E | C |
| ATOM | 6858 | CB | LEU | E | 316 | −27.434 | 51.713 | 66.847 | 1.00 | 16.53 | E | C |
| ATOM | 6859 | CG | LEU | E | 316 | −27.891 | 52.069 | 68.263 | 1.00 | 15.55 | E | C |
| ATOM | 6860 | CD1 | LEU | E | 316 | −26.879 | 51.527 | 69.261 | 1.00 | 16.31 | E | C |
| ATOM | 6861 | CD2 | LEU | E | 316 | −28.026 | 53.572 | 68.410 | 1.00 | 13.05 | E | C |
| ATOM | 6862 | C | LEU | E | 316 | −29.080 | 49.900 | 66.488 | 1.00 | 19.19 | E | C |
| ATOM | 6863 | O | LEU | E | 316 | −29.585 | 49.275 | 67.417 | 1.00 | 20.54 | E | O |
| ATOM | 6864 | N | ARG | E | 317 | −29.773 | 50.324 | 65.443 | 1.00 | 21.79 | E | N |
| ATOM | 6865 | CA | ARG | E | 317 | −31.195 | 50.073 | 65.303 | 1.00 | 20.65 | E | C |
| ATOM | 6866 | CB | ARG | E | 317 | −31.686 | 50.733 | 64.016 | 1.00 | 25.84 | E | C |
| ATOM | 6867 | CG | ARG | E | 317 | −33.180 | 50.707 | 63.802 | 1.00 | 31.96 | E | C |
| ATOM | 6868 | CD | ARG | E | 317 | −33.594 | 51.767 | 62.783 | 1.00 | 37.49 | E | C |
| ATOM | 6869 | NE | ARG | E | 317 | −32.823 | 51.692 | 61.540 | 1.00 | 43.38 | E | N |
| ATOM | 6870 | CZ | ARG | E | 317 | −32.094 | 52.692 | 61.051 | 1.00 | 45.56 | E | C |
| ATOM | 6871 | NH1 | ARG | E | 317 | −32.037 | 53.847 | 61.704 | 1.00 | 46.72 | E | N |
| ATOM | 6872 | NH2 | ARG | E | 317 | −31.430 | 52.544 | 59.910 | 1.00 | 43.93 | E | N |
| ATOM | 6873 | C | ARG | E | 317 | −31.499 | 48.576 | 65.275 | 1.00 | 21.06 | E | C |
| ATOM | 6874 | O | ARG | E | 317 | −32.467 | 48.122 | 65.880 | 1.00 | 21.15 | E | O |
| ATOM | 6875 | N | PHE | E | 318 | −30.664 | 47.806 | 64.584 | 1.00 | 20.15 | E | N |
| ATOM | 6876 | CA | PHE | E | 318 | −30.884 | 46.369 | 64.473 | 1.00 | 19.57 | E | C |
| ATOM | 6877 | CB | PHE | E | 318 | −30.053 | 45.780 | 63.332 | 1.00 | 18.17 | E | C |
| ATOM | 6878 | CG | PHE | E | 318 | −30.180 | 44.290 | 63.204 | 1.00 | 18.23 | E | C |
| ATOM | 6879 | CD1 | PHE | E | 318 | −31.152 | 43.730 | 62.382 | 1.00 | 19.82 | E | C |
| ATOM | 6880 | CD2 | PHE | E | 318 | −29.333 | 43.443 | 63.913 | 1.00 | 18.66 | E | C |
| ATOM | 6881 | CE1 | PHE | E | 318 | −31.283 | 42.342 | 62.265 | 1.00 | 18.80 | E | C |
| ATOM | 6882 | CE2 | PHE | E | 318 | −29.453 | 42.057 | 63.806 | 1.00 | 18.06 | E | C |
| ATOM | 6883 | CZ | PHE | E | 318 | −30.433 | 41.506 | 62.978 | 1.00 | 18.57 | E | C |
| ATOM | 6884 | C | PHE | E | 318 | −30.575 | 45.610 | 65.753 | 1.00 | 21.23 | E | C |
| ATOM | 6885 | O | PHE | E | 318 | −31.220 | 44.600 | 66.060 | 1.00 | 22.05 | E | O |
| ATOM | 6886 | N | ILE | E | 319 | −29.581 | 46.073 | 66.498 | 1.00 | 19.53 | E | N |
| ATOM | 6887 | CA | ILE | E | 319 | −29.241 | 45.397 | 67.734 | 1.00 | 19.42 | E | C |
| ATOM | 6888 | CB | ILE | E | 319 | −28.034 | 46.056 | 68.411 | 1.00 | 18.06 | E | C |
| ATOM | 6889 | CG2 | ILE | E | 319 | −27.842 | 45.481 | 69.805 | 1.00 | 19.60 | E | C |
| ATOM | 6890 | CG1 | ILE | E | 319 | −26.785 | 45.817 | 67.560 | 1.00 | 14.63 | E | C |
| ATOM | 6891 | CD1 | ILE | E | 319 | −25.531 | 46.416 | 68.125 | 1.00 | 11.61 | E | C |
| ATOM | 6892 | C | ILE | E | 319 | −30.448 | 45.443 | 68.663 | 1.00 | 20.81 | E | C |
| ATOM | 6893 | O | ILE | E | 319 | −30.866 | 44.414 | 69.199 | 1.00 | 22.62 | E | O |
| ATOM | 6894 | N | LYS | E | 320 | −31.020 | 46.632 | 68.827 | 1.00 | 19.26 | E | N |
| ATOM | 6895 | CA | LYS | E | 320 | −32.180 | 46.805 | 69.686 | 1.00 | 20.47 | E | C |
| ATOM | 6896 | CB | LYS | E | 320 | −32.577 | 48.276 | 69.741 | 1.00 | 17.02 | E | C |
| ATOM | 6897 | CG | LYS | E | 320 | −31.474 | 49.186 | 70.234 | 1.00 | 14.35 | E | C |
| ATOM | 6898 | CD | LYS | E | 320 | −31.999 | 50.584 | 70.494 | 1.00 | 15.83 | E | C |
| ATOM | 6899 | CE | LYS | E | 320 | −30.952 | 51.453 | 71.157 | 1.00 | 18.13 | E | C |
| ATOM | 6900 | NZ | LYS | E | 320 | −31.332 | 52.889 | 71.102 | 1.00 | 22.80 | E | N |
| ATOM | 6901 | C | LYS | E | 320 | −33.360 | 45.965 | 69.206 | 1.00 | 22.71 | E | C |
| ATOM | 6902 | O | LYS | E | 320 | −34.059 | 45.343 | 70.007 | 1.00 | 26.06 | E | O |
| ATOM | 6903 | N | LYS | E | 321 | −33.579 | 45.940 | 67.899 | 1.00 | 23.42 | E | N |
| ATOM | 6904 | CA | LYS | E | 321 | −34.676 | 45.164 | 67.340 | 1.00 | 23.71 | E | C |
| ATOM | 6905 | CB | LYS | E | 321 | −34.789 | 45.417 | 65.834 | 1.00 | 24.49 | E | C |
| ATOM | 6906 | CG | LYS | E | 321 | −36.118 | 44.994 | 65.227 | 1.00 | 26.25 | E | C |
| ATOM | 6907 | CD | LYS | E | 321 | −37.292 | 45.644 | 65.946 | 1.00 | 33.47 | E | C |
| ATOM | 6908 | CE | LYS | E | 321 | −38.621 | 45.342 | 65.254 | 1.00 | 36.07 | E | C |
| ATOM | 6909 | NZ | LYS | E | 321 | −38.608 | 44.026 | 64.547 | 1.00 | 41.06 | E | N |
| ATOM | 6910 | C | LYS | E | 321 | −34.476 | 43.674 | 67.603 | 1.00 | 23.08 | E | C |
| ATOM | 6911 | O | LYS | E | 321 | −35.427 | 42.957 | 67.909 | 1.00 | 22.62 | E | O |
| ATOM | 6912 | N | SER | E | 322 | −33.237 | 43.212 | 67.488 | 1.00 | 23.33 | E | N |
| ATOM | 6913 | CA | SER | E | 322 | −32.938 | 41.805 | 67.718 | 1.00 | 23.70 | E | C |
| ATOM | 6914 | CB | SER | E | 322 | −31.469 | 41.513 | 67.393 | 1.00 | 20.72 | E | C |
| ATOM | 6915 | OG | SER | E | 322 | −30.601 | 42.095 | 68.347 | 1.00 | 16.50 | E | O |
| ATOM | 6916 | C | SER | E | 322 | −33.249 | 41.391 | 69.159 | 1.00 | 25.71 | E | C |
| ATOM | 6917 | O | SER | E | 322 | −33.672 | 40.262 | 69.413 | 1.00 | 24.66 | E | O |
| ATOM | 6918 | N | TYR | E | 323 | −33.040 | 42.306 | 70.100 | 1.00 | 28.44 | E | N |
| ATOM | 6919 | CA | TYR | E | 323 | −33.314 | 42.017 | 71.502 | 1.00 | 29.43 | E | C |
| ATOM | 6920 | CB | TYR | E | 323 | −32.712 | 43.100 | 72.392 | 1.00 | 29.08 | E | C |
| ATOM | 6921 | CG | TYR | E | 323 | −32.965 | 42.881 | 73.864 | 1.00 | 32.48 | E | C |
| ATOM | 6922 | CD1 | TYR | E | 323 | −34.081 | 43.433 | 74.489 | 1.00 | 34.60 | E | C |
| ATOM | 6923 | CE1 | TYR | E | 323 | −34.313 | 43.244 | 75.848 | 1.00 | 35.96 | E | C |
| ATOM | 6924 | CD2 | TYR | E | 323 | −32.083 | 42.131 | 74.638 | 1.00 | 34.33 | E | C |
| ATOM | 6925 | CE2 | TYR | E | 323 | −32.303 | 41.935 | 75.996 | 1.00 | 36.34 | E | C |
| ATOM | 6926 | CZ | TYR | E | 323 | −33.420 | 42.496 | 76.597 | 1.00 | 38.31 | E | C |
| ATOM | 6927 | OH | TYR | E | 323 | −33.645 | 42.315 | 77.945 | 1.00 | 40.18 | E | O |
| ATOM | 6928 | C | TYR | E | 323 | −34.817 | 41.944 | 71.735 | 1.00 | 29.95 | E | C |
| ATOM | 6929 | O | TYR | E | 323 | −35.314 | 41.064 | 72.438 | 1.00 | 29.53 | E | O |
| ATOM | 6930 | N | GLN | E | 324 | −35.537 | 42.876 | 71.129 | 1.00 | 30.55 | E | N |
| ATOM | 6931 | CA | GLN | E | 324 | −36.979 | 42.934 | 71.263 | 1.00 | 29.96 | E | C |
| ATOM | 6932 | CB | GLN | E | 324 | −37.520 | 44.119 | 70.452 | 1.00 | 33.40 | E | C |
| ATOM | 6933 | CG | GLN | E | 324 | −39.036 | 44.171 | 70.310 | 1.00 | 39.05 | E | C |
| ATOM | 6934 | CD | GLN | E | 324 | −39.480 | 44.887 | 69.041 | 1.00 | 44.94 | E | C |
| ATOM | 6935 | OE1 | GLN | E | 324 | −39.056 | 46.015 | 68.766 | 1.00 | 46.05 | E | O |
| ATOM | 6936 | NE2 | GLN | E | 324 | −40.338 | 44.230 | 68.257 | 1.00 | 45.34 | E | N |
| ATOM | 6937 | C | GLN | E | 324 | −37.652 | 41.639 | 70.820 | 1.00 | 28.63 | E | C |
| ATOM | 6938 | O | GLN | E | 324 | −38.637 | 41.217 | 71.418 | 1.00 | 28.24 | E | O |
| ATOM | 6939 | N | VAL | E | 325 | −37.116 | 40.994 | 69.789 | 1.00 | 28.27 | E | N |
| ATOM | 6940 | CA | VAL | E | 325 | −37.729 | 39.766 | 69.292 | 1.00 | 28.90 | E | C |
| ATOM | 6941 | CB | VAL | E | 325 | −37.994 | 39.848 | 67.755 | 1.00 | 27.23 | E | C |
| ATOM | 6942 | CG1 | VAL | E | 325 | −38.253 | 41.282 | 67.346 | 1.00 | 25.17 | E | C |
| ATOM | 6943 | CG2 | VAL | E | 325 | −36.829 | 39.268 | 66.982 | 1.00 | 24.15 | E | C |
| ATOM | 6944 | C | VAL | E | 325 | −36.999 | 38.450 | 69.582 | 1.00 | 30.99 | E | C |
| ATOM | 6945 | O | VAL | E | 325 | −37.614 | 37.382 | 69.549 | 1.00 | 32.46 | E | O |
| ATOM | 6946 | N | ASP | E | 326 | −35.702 | 38.512 | 69.867 | 1.00 | 29.57 | E | N |
| ATOM | 6947 | CA | ASP | E | 326 | −34.944 | 37.292 | 70.134 | 1.00 | 28.06 | E | C |
| ATOM | 6948 | CB | ASP | E | 326 | −33.843 | 37.105 | 69.082 | 1.00 | 29.19 | E | C |
| ATOM | 6949 | CG | ASP | E | 326 | −34.360 | 36.517 | 67.775 | 1.00 | 31.15 | E | C |
| ATOM | 6950 | OD1 | ASP | E | 326 | −35.528 | 36.051 | 67.731 | 1.00 | 33.72 | E | O |
| ATOM | 6951 | OD2 | ASP | E | 326 | −33.586 | 36.521 | 66.785 | 1.00 | 30.79 | E | O |
| ATOM | 6952 | C | ASP | E | 326 | −34.302 | 37.319 | 71.510 | 1.00 | 28.23 | E | C |
| ATOM | 6953 | O | ASP | E | 326 | −33.314 | 36.625 | 71.745 | 1.00 | 27.12 | E | O |
| ATOM | 6954 | N | ALA | E | 327 | −34.854 | 38.118 | 72.420 | 1.00 | 29.44 | E | N |
| ATOM | 6955 | CA | ALA | E | 327 | −34.305 | 38.223 | 73.774 | 1.00 | 30.52 | E | C |
| ATOM | 6956 | CB | ALA | E | 327 | −35.239 | 39.048 | 74.654 | 1.00 | 27.81 | E | C |
| ATOM | 6957 | C | ALA | E | 327 | −34.021 | 36.875 | 74.443 | 1.00 | 30.22 | E | C |
| ATOM | 6958 | O | ALA | E | 327 | −33.033 | 36.738 | 75.172 | 1.00 | 29.93 | E | O |
| ATOM | 6959 | N | ASP | E | 328 | −34.871 | 35.881 | 74.187 | 1.00 | 32.75 | E | N |
| ATOM | 6960 | CA | ASP | E | 328 | −34.707 | 34.563 | 74.801 | 1.00 | 33.81 | E | C |
| ATOM | 6961 | CB | ASP | E | 328 | −36.024 | 34.126 | 75.453 | 1.00 | 33.46 | E | C |
| ATOM | 6962 | CG | ASP | E | 328 | −36.497 | 35.101 | 76.522 | 1.00 | 35.21 | E | C |
| ATOM | 6963 | OD1 | ASP | E | 328 | −35.702 | 35.444 | 77.427 | 1.00 | 35.55 | E | O |
| ATOM | 6964 | OD2 | ASP | E | 328 | −37.667 | 35.528 | 76.454 | 1.00 | 37.19 | E | O |
| ATOM | 6965 | C | ASP | E | 328 | −34.207 | 33.461 | 73.872 | 1.00 | 32.70 | E | C |
| ATOM | 6966 | O | ASP | E | 328 | −34.308 | 32.279 | 74.198 | 1.00 | 33.99 | E | O |
| ATOM | 6967 | N | ARG | E | 329 | −33.665 | 33.852 | 72.723 | 1.00 | 31.26 | E | N |
| ATOM | 6968 | CA | ARG | E | 329 | −33.135 | 32.904 | 71.752 | 1.00 | 27.95 | E | C |
| ATOM | 6969 | CB | ARG | E | 329 | −33.061 | 33.559 | 70.366 | 1.00 | 30.75 | E | C |
| ATOM | 6970 | CG | ARG | E | 329 | −33.300 | 32.624 | 69.183 | 1.00 | 34.31 | E | C |
| ATOM | 6971 | CD | ARG | E | 329 | −32.139 | 32.641 | 68.184 | 1.00 | 31.61 | E | C |
| ATOM | 6972 | NE | ARG | E | 329 | −32.411 | 33.509 | 67.039 | 1.00 | 32.79 | E | N |
| ATOM | 6973 | CZ | ARG | E | 329 | −32.073 | 33.237 | 65.780 | 1.00 | 31.60 | E | C |
| ATOM | 6974 | NH1 | ARG | E | 329 | −31.449 | 32.110 | 65.471 | 1.00 | 31.57 | E | N |
| ATOM | 6975 | NH2 | ARG | E | 329 | −32.351 | 34.106 | 64.822 | 1.00 | 31.86 | E | N |
| ATOM | 6976 | C | ARG | E | 329 | −31.729 | 32.517 | 72.192 | 1.00 | 27.86 | E | C |
| ATOM | 6977 | O | ARG | E | 329 | −30.951 | 33.380 | 72.607 | 1.00 | 25.04 | E | O |
| ATOM | 6978 | N | VAL | E | 330 | −31.402 | 31.228 | 72.120 | 1.00 | 28.26 | E | N |
| ATOM | 6979 | CA | VAL | E | 330 | −30.061 | 30.783 | 72.482 | 1.00 | 27.48 | E | C |
| ATOM | 6980 | CB | VAL | E | 330 | −29.970 | 29.258 | 72.609 | 1.00 | 28.48 | E | C |
| ATOM | 6981 | CG1 | VAL | E | 330 | −28.535 | 28.850 | 72.904 | 1.00 | 26.24 | E | C |
| ATOM | 6982 | CG2 | VAL | E | 330 | −30.888 | 28.782 | 73.719 | 1.00 | 29.64 | E | C |
| ATOM | 6983 | C | VAL | E | 330 | −29.218 | 31.248 | 71.310 | 1.00 | 29.59 | E | C |
| ATOM | 6984 | O | VAL | E | 330 | −29.454 | 30.850 | 70.164 | 1.00 | 29.95 | E | O |
| ATOM | 6985 | N | VAL | E | 331 | −28.231 | 32.090 | 71.589 | 1.00 | 30.19 | E | N |
| ATOM | 6986 | CA | VAL | E | 331 | −27.425 | 32.648 | 70.518 | 1.00 | 29.91 | E | C |
| ATOM | 6987 | CB | VAL | E | 331 | −27.839 | 34.116 | 70.316 | 1.00 | 26.71 | E | C |
| ATOM | 6988 | CG1 | VAL | E | 331 | −26.933 | 35.032 | 71.108 | 1.00 | 24.09 | E | C |
| ATOM | 6989 | CG2 | VAL | E | 331 | −27.839 | 34.456 | 68.855 | 1.00 | 30.43 | E | C |
| ATOM | 6990 | C | VAL | E | 331 | −25.911 | 32.560 | 70.692 | 1.00 | 30.96 | E | C |
| ATOM | 6991 | O | VAL | E | 331 | −25.156 | 32.748 | 69.740 | 1.00 | 27.65 | E | O |
| ATOM | 6992 | N | TYR | E | 332 | −25.473 | 32.260 | 71.907 | 1.00 | 35.46 | E | N |
| ATOM | 6993 | CA | TYR | E | 332 | −24.052 | 32.179 | 72.216 | 1.00 | 37.66 | E | C |
| ATOM | 6994 | CB | TYR | E | 332 | −23.675 | 33.396 | 73.058 | 1.00 | 38.09 | E | C |
| ATOM | 6995 | CG | TYR | E | 332 | −22.236 | 33.480 | 73.504 | 1.00 | 39.31 | E | C |
| ATOM | 6996 | CD1 | TYR | E | 332 | −21.288 | 34.159 | 72.737 | 1.00 | 38.94 | E | C |
| ATOM | 6997 | CE1 | TYR | E | 332 | −19.976 | 34.318 | 73.187 | 1.00 | 40.75 | E | C |
| ATOM | 6998 | CD2 | TYR | E | 332 | −21.835 | 32.951 | 74.737 | 1.00 | 41.09 | E | C |
| ATOM | 6999 | CE2 | TYR | E | 332 | −20.523 | 33.105 | 75.199 | 1.00 | 42.14 | E | C |
| ATOM | 7000 | CZ | TYR | E | 332 | −19.602 | 33.791 | 74.419 | 1.00 | 41.28 | E | C |
| ATOM | 7001 | OH | TYR | E | 332 | −18.317 | 33.963 | 74.876 | 1.00 | 43.20 | E | O |
| ATOM | 7002 | C | TYR | E | 332 | −23.776 | 30.890 | 72.975 | 1.00 | 41.57 | E | C |
| ATOM | 7003 | O | TYR | E | 332 | −24.646 | 30.392 | 73.691 | 1.00 | 44.48 | E | O |
| ATOM | 7004 | N | SER | E | 333 | −22.575 | 30.343 | 72.823 | 1.00 | 43.34 | E | N |
| ATOM | 7005 | CA | SER | E | 333 | −22.245 | 29.105 | 73.511 | 1.00 | 49.30 | E | C |
| ATOM | 7006 | CB | SER | E | 333 | −21.825 | 28.034 | 72.503 | 1.00 | 46.88 | E | C |
| ATOM | 7007 | OG | SER | E | 333 | −21.203 | 26.944 | 73.164 | 1.00 | 47.14 | E | O |
| ATOM | 7008 | C | SER | E | 333 | −21.161 | 29.242 | 74.579 | 1.00 | 55.11 | E | C |
| ATOM | 7009 | O | SER | E | 333 | −20.052 | 29.713 | 74.303 | 1.00 | 55.52 | E | O |
| ATOM | 7010 | N | THR | E | 334 | −21.501 | 28.832 | 75.801 | 1.00 | 58.77 | E | N |
| ATOM | 7011 | CA | THR | E | 334 | −20.566 | 28.858 | 76.926 | 1.00 | 60.70 | E | C |
| ATOM | 7012 | CB | THR | E | 334 | −20.883 | 30.003 | 77.940 | 1.00 | 61.02 | E | C |
| ATOM | 7013 | OG1 | THR | E | 334 | −19.729 | 30.849 | 78.073 | 1.00 | 58.88 | E | O |
| ATOM | 7014 | CG2 | THR | E | 334 | −21.246 | 29.440 | 79.323 | 1.00 | 58.62 | E | C |
| ATOM | 7015 | C | THR | E | 334 | −20.685 | 27.507 | 77.615 | 1.00 | 61.97 | E | C |
| ATOM | 7016 | O | THR | E | 334 | −21.783 | 26.948 | 77.714 | 1.00 | 59.97 | E | O |
| ATOM | 7017 | N | LYS | E | 335 | −19.551 | 26.993 | 78.081 | 1.00 | 63.01 | E | N |
| ATOM | 7018 | CA | LYS | E | 335 | −19.496 | 25.696 | 78.743 | 1.00 | 64.06 | E | C |
| ATOM | 7019 | CB | LYS | E | 335 | −18.271 | 25.625 | 79.657 | 1.00 | 61.66 | E | C |
| ATOM | 7020 | CG | LYS | E | 335 | −17.604 | 24.251 | 79.676 | 1.00 | 62.03 | E | C |
| ATOM | 7021 | CD | LYS | E | 335 | −18.593 | 23.117 | 79.978 | 1.00 | 59.70 | E | C |
| ATOM | 7022 | CE | LYS | E | 335 | −18.468 | 21.984 | 78.963 | 1.00 | 59.74 | E | C |
| ATOM | 7023 | NZ | LYS | E | 335 | −18.514 | 20.628 | 79.596 | 1.00 | 58.47 | E | N |
| ATOM | 7024 | C | LYS | E | 335 | −20.741 | 25.297 | 79.539 | 1.00 | 65.36 | E | C |
| ATOM | 7025 | O | LYS | E | 335 | −21.647 | 24.642 | 79.008 | 1.00 | 66.81 | E | O |
| ATOM | 7026 | N | GLU | E | 336 | −20.782 | 25.684 | 80.812 | 1.00 | 66.17 | E | N |
| ATOM | 7027 | CA | GLU | E | 336 | −21.900 | 25.326 | 81.680 | 1.00 | 65.97 | E | C |
| ATOM | 7028 | CB | GLU | E | 336 | −21.686 | 25.886 | 83.092 | 1.00 | 66.82 | E | C |
| ATOM | 7029 | CG | GLU | E | 336 | −21.830 | 24.834 | 84.198 | 1.00 | 67.37 | E | C |
| ATOM | 7030 | CD | GLU | E | 336 | −21.867 | 23.401 | 83.665 | 1.00 | 68.22 | E | C |
| ATOM | 7031 | OE1 | GLU | E | 336 | −22.971 | 22.915 | 83.323 | 1.00 | 66.29 | E | O |
| ATOM | 7032 | OE2 | GLU | E | 336 | −20.789 | 22.767 | 83.591 | 1.00 | 67.72 | E | O |
| ATOM | 7033 | C | GLU | E | 336 | −23.270 | 25.743 | 81.163 | 1.00 | 64.80 | E | C |
| ATOM | 7034 | O | GLU | E | 336 | −24.296 | 25.267 | 81.662 | 1.00 | 64.93 | E | O |
| ATOM | 7035 | N | LYS | E | 337 | −23.296 | 26.621 | 80.164 | 1.00 | 62.72 | E | N |
| ATOM | 7036 | CA | LYS | E | 337 | −24.571 | 27.056 | 79.609 | 1.00 | 59.83 | E | C |
| ATOM | 7037 | CB | LYS | E | 337 | −25.396 | 27.766 | 80.690 | 1.00 | 59.11 | E | C |
| ATOM | 7038 | CG | LYS | E | 337 | −26.840 | 28.017 | 80.302 | 1.00 | 57.92 | E | C |
| ATOM | 7039 | CD | LYS | E | 337 | −27.483 | 29.046 | 81.218 | 1.00 | 57.29 | E | C |
| ATOM | 7040 | CE | LYS | E | 337 | −28.749 | 29.617 | 80.587 | 1.00 | 55.94 | E | C |
| ATOM | 7041 | NZ | LYS | E | 337 | −30.004 | 29.136 | 81.231 | 1.00 | 53.24 | E | N |
| ATOM | 7042 | C | LYS | E | 337 | −24.443 | 27.971 | 78.396 | 1.00 | 57.87 | E | C |
| ATOM | 7043 | O | LYS | E | 337 | −23.760 | 28.995 | 78.443 | 1.00 | 59.26 | E | O |
| ATOM | 7044 | N | ASN | E | 338 | −25.090 | 27.588 | 77.302 | 1.00 | 52.89 | E | N |
| ATOM | 7045 | CA | ASN | E | 338 | −25.087 | 28.422 | 76.114 | 1.00 | 46.16 | E | C |
| ATOM | 7046 | CB | ASN | E | 338 | −25.692 | 27.667 | 74.929 | 1.00 | 48.15 | E | C |
| ATOM | 7047 | CG | ASN | E | 338 | −24.943 | 26.383 | 74.609 | 1.00 | 50.72 | E | C |
| ATOM | 7048 | OD1 | ASN | E | 338 | −23.706 | 26.346 | 74.634 | 1.00 | 53.11 | E | O |
| ATOM | 7049 | ND2 | ASN | E | 338 | −25.688 | 25.319 | 74.305 | 1.00 | 51.03 | E | N |
| ATOM | 7050 | C | ASN | E | 338 | −26.009 | 29.541 | 76.572 | 1.00 | 42.11 | E | C |
| ATOM | 7051 | O | ASN | E | 338 | −26.954 | 29.288 | 77.312 | 1.00 | 41.76 | E | O |
| ATOM | 7052 | N | LEU | E | 339 | −25.740 | 30.771 | 76.155 | 1.00 | 37.02 | E | N |
| ATOM | 7053 | CA | LEU | E | 339 | −26.561 | 31.893 | 76.587 | 1.00 | 33.98 | E | C |
| ATOM | 7054 | CB | LEU | E | 339 | −25.668 | 33.075 | 76.946 | 1.00 | 35.53 | E | C |
| ATOM | 7055 | CG | LEU | E | 339 | −24.309 | 32.700 | 77.534 | 1.00 | 34.81 | E | C |
| ATOM | 7056 | CD1 | LEU | E | 339 | −23.398 | 33.905 | 77.527 | 1.00 | 32.45 | E | C |
| ATOM | 7057 | CD2 | LEU | E | 339 | −24.504 | 32.171 | 78.950 | 1.00 | 38.35 | E | C |
| ATOM | 7058 | C | LEU | E | 339 | −27.594 | 32.364 | 75.591 | 1.00 | 30.31 | E | C |
| ATOM | 7059 | O | LEU | E | 339 | −27.466 | 32.139 | 74.398 | 1.00 | 31.43 | E | O |
| ATOM | 7060 | N | THR | E | 340 | −28.630 | 33.016 | 76.104 | 1.00 | 29.60 | E | N |
| ATOM | 7061 | CA | THR | E | 340 | −29.664 | 33.577 | 75.262 | 1.00 | 29.54 | E | C |
| ATOM | 7062 | CB | THR | E | 340 | −31.011 | 33.694 | 75.997 | 1.00 | 28.42 | E | C |
| ATOM | 7063 | OG1 | THR | E | 340 | −30.856 | 34.521 | 77.154 | 1.00 | 25.76 | E | O |
| ATOM | 7064 | CG2 | THR | E | 340 | −31.511 | 32.327 | 76.412 | 1.00 | 28.14 | E | C |
| ATOM | 7065 | C | THR | E | 340 | −29.148 | 34.980 | 74.962 | 1.00 | 32.18 | E | C |
| ATOM | 7066 | O | THR | E | 340 | −28.163 | 35.418 | 75.563 | 1.00 | 31.86 | E | O |
| ATOM | 7067 | N | LEU | E | 341 | −29.789 | 35.680 | 74.033 | 1.00 | 31.42 | E | N |
| ATOM | 7068 | CA | LEU | E | 341 | −29.365 | 37.032 | 73.702 | 1.00 | 28.71 | E | C |
| ATOM | 7069 | CB | LEU | E | 341 | −30.337 | 37.664 | 72.696 | 1.00 | 29.92 | E | C |
| ATOM | 7070 | CG | LEU | E | 341 | −30.016 | 39.076 | 72.192 | 1.00 | 28.83 | E | C |
| ATOM | 7071 | CD1 | LEU | E | 341 | −28.548 | 39.166 | 71.807 | 1.00 | 25.91 | E | C |
| ATOM | 7072 | CD2 | LEU | E | 341 | −30.896 | 39.406 | 71.001 | 1.00 | 25.76 | E | C |
| ATOM | 7073 | C | LEU | E | 341 | −29.328 | 37.867 | 74.979 | 1.00 | 28.67 | E | C |
| ATOM | 7074 | O | LEU | E | 341 | −28.385 | 38.624 | 75.215 | 1.00 | 27.05 | E | O |
| ATOM | 7075 | N | LYS | E | 342 | −30.362 | 37.714 | 75.803 | 1.00 | 30.02 | E | N |
| ATOM | 7076 | CA | LYS | E | 342 | −30.468 | 38.445 | 77.059 | 1.00 | 27.76 | E | C |
| ATOM | 7077 | CB | LYS | E | 342 | −31.779 | 38.088 | 77.757 | 1.00 | 28.91 | E | C |
| ATOM | 7078 | CG | LYS | E | 342 | −32.185 | 39.063 | 78.844 | 1.00 | 33.93 | E | C |
| ATOM | 7079 | CD | LYS | E | 342 | −33.524 | 38.671 | 79.460 | 1.00 | 39.30 | E | C |
| ATOM | 7080 | CE | LYS | E | 342 | −34.366 | 39.891 | 79.833 | 1.00 | 43.97 | E | C |
| ATOM | 7081 | NZ | LYS | E | 342 | −35.615 | 40.004 | 79.008 | 1.00 | 46.16 | E | N |
| ATOM | 7082 | C | LYS | E | 342 | −29.296 | 38.131 | 77.980 | 1.00 | 25.84 | E | C |
| ATOM | 7083 | O | LYS | E | 342 | −28.642 | 39.033 | 78.498 | 1.00 | 22.85 | E | O |
| ATOM | 7084 | N | GLN | E | 343 | −29.031 | 36.846 | 78.176 | 1.00 | 23.85 | E | N |
| ATOM | 7085 | CA | GLN | E | 343 | −27.945 | 36.416 | 79.044 | 1.00 | 27.95 | E | C |
| ATOM | 7086 | CB | GLN | E | 343 | −27.901 | 34.894 | 79.126 | 1.00 | 28.15 | E | C |
| ATOM | 7087 | CG | GLN | E | 343 | −29.041 | 34.288 | 79.909 | 1.00 | 32.76 | E | C |
| ATOM | 7088 | CD | GLN | E | 343 | −29.084 | 32.786 | 79.775 | 1.00 | 33.35 | E | C |
| ATOM | 7089 | OE1 | GLN | E | 343 | −28.140 | 32.173 | 79.284 | 1.00 | 34.16 | E | O |
| ATOM | 7090 | NE2 | GLN | E | 343 | −30.182 | 32.183 | 80.208 | 1.00 | 35.67 | E | N |
| ATOM | 7091 | C | GLN | E | 343 | −26.593 | 36.921 | 78.573 | 1.00 | 30.21 | E | C |
| ATOM | 7092 | O | GLN | E | 343 | −25.703 | 37.203 | 79.384 | 1.00 | 31.64 | E | O |
| ATOM | 7093 | N | LEU | E | 344 | −26.427 | 37.016 | 77.259 | 1.00 | 30.22 | E | N |
| ATOM | 7094 | CA | LEU | E | 344 | −25.171 | 37.488 | 76.699 | 1.00 | 28.95 | E | C |
| ATOM | 7095 | CB | LEU | E | 344 | −25.170 | 37.328 | 75.175 | 1.00 | 26.81 | E | C |
| ATOM | 7096 | CG | LEU | E | 344 | −23.898 | 37.794 | 74.457 | 1.00 | 25.35 | E | C |
| ATOM | 7097 | CD1 | LEU | E | 344 | −22.670 | 37.222 | 75.149 | 1.00 | 20.54 | E | C |
| ATOM | 7098 | CD2 | LEU | E | 344 | −23.945 | 37.360 | 72.995 | 1.00 | 23.63 | E | C |
| ATOM | 7099 | C | LEU | E | 344 | −24.977 | 38.950 | 77.073 | 1.00 | 28.21 | E | C |
| ATOM | 7100 | O | LEU | E | 344 | −23.891 | 39.356 | 77.476 | 1.00 | 27.97 | E | O |
| ATOM | 7101 | N | PHE | E | 345 | −26.036 | 39.740 | 76.944 | 1.00 | 28.10 | E | N |
| ATOM | 7102 | CA | PHE | E | 345 | −25.961 | 41.150 | 77.291 | 1.00 | 29.00 | E | C |
| ATOM | 7103 | CB | PHE | E | 345 | −27.221 | 41.881 | 76.821 | 1.00 | 29.25 | E | C |
| ATOM | 7104 | CG | PHE | E | 345 | −27.181 | 42.269 | 75.369 | 1.00 | 30.95 | E | C |
| ATOM | 7105 | CD1 | PHE | E | 345 | −26.199 | 43.135 | 74.896 | 1.00 | 30.72 | E | C |
| ATOM | 7106 | CD2 | PHE | E | 345 | −28.104 | 41.751 | 74.463 | 1.00 | 29.52 | E | C |
| ATOM | 7107 | CE1 | PHE | E | 345 | −26.136 | 43.477 | 73.543 | 1.00 | 25.96 | E | C |
| ATOM | 7108 | CE2 | PHE | E | 345 | −28.044 | 42.091 | 73.109 | 1.00 | 25.40 | E | C |
| ATOM | 7109 | CZ | PHE | E | 345 | −27.060 | 42.954 | 72.653 | 1.00 | 23.53 | E | C |
| ATOM | 7110 | C | PHE | E | 345 | −25.776 | 41.322 | 78.799 | 1.00 | 31.96 | E | C |
| ATOM | 7111 | O | PHE | E | 345 | −25.174 | 42.302 | 79.248 | 1.00 | 29.59 | E | O |
| ATOM | 7112 | N | ASP | E | 346 | −26.295 | 40.368 | 79.575 | 1.00 | 33.54 | E | N |
| ATOM | 7113 | CA | ASP | E | 346 | −26.160 | 40.399 | 81.032 | 1.00 | 33.73 | E | C |
| ATOM | 7114 | CB | ASP | E | 346 | −26.982 | 39.284 | 81.676 | 1.00 | 37.26 | E | C |
| ATOM | 7115 | CG | ASP | E | 346 | −28.386 | 39.722 | 82.031 | 1.00 | 40.92 | E | C |
| ATOM | 7116 | OD1 | ASP | E | 346 | −28.778 | 40.845 | 81.651 | 1.00 | 43.08 | E | O |
| ATOM | 7117 | OD2 | ASP | E | 346 | −29.099 | 38.937 | 82.689 | 1.00 | 44.74 | E | O |
| ATOM | 7118 | C | ASP | E | 346 | −24.695 | 40.177 | 81.359 | 1.00 | 32.10 | E | C |
| ATOM | 7119 | O | ASP | E | 346 | −24.120 | 40.855 | 82.198 | 1.00 | 31.71 | E | O |
| ATOM | 7120 | N | LYS | E | 347 | −24.104 | 39.205 | 80.678 | 1.00 | 32.64 | E | N |
| ATOM | 7121 | CA | LYS | E | 347 | −22.702 | 38.862 | 80.854 | 1.00 | 34.01 | E | C |
| ATOM | 7122 | CB | LYS | E | 347 | −22.374 | 37.632 | 80.005 | 1.00 | 36.37 | E | C |
| ATOM | 7123 | CG | LYS | E | 347 | −21.069 | 36.944 | 80.358 | 1.00 | 41.40 | E | C |
| ATOM | 7124 | CD | LYS | E | 347 | −20.080 | 37.030 | 79.205 | 1.00 | 43.73 | E | C |
| ATOM | 7125 | CE | LYS | E | 347 | −19.910 | 35.689 | 78.516 | 1.00 | 45.32 | E | C |
| ATOM | 7126 | NZ | LYS | E | 347 | −18.512 | 35.192 | 78.619 | 1.00 | 47.52 | E | N |
| ATOM | 7127 | C | LYS | E | 347 | −21.815 | 40.033 | 80.436 | 1.00 | 34.98 | E | C |
| ATOM | 7128 | O | LYS | E | 347 | −20.703 | 40.200 | 80.936 | 1.00 | 34.46 | E | O |
| ATOM | 7129 | N | LEU | E | 348 | −22.315 | 40.850 | 79.517 | 1.00 | 36.12 | E | N |
| ATOM | 7130 | CA | LEU | E | 348 | −21.556 | 41.997 | 79.034 | 1.00 | 35.42 | E | C |
| ATOM | 7131 | CB | LEU | E | 348 | −21.874 | 42.261 | 77.560 | 1.00 | 34.90 | E | C |
| ATOM | 7132 | CG | LEU | E | 348 | −21.290 | 41.254 | 76.560 | 1.00 | 33.95 | E | C |
| ATOM | 7133 | CD1 | LEU | E | 348 | −21.967 | 41.430 | 75.211 | 1.00 | 32.60 | E | C |
| ATOM | 7134 | CD2 | LEU | E | 348 | −19.784 | 41.444 | 76.440 | 1.00 | 28.48 | E | C |
| ATOM | 7135 | C | LEU | E | 348 | −21.851 | 43.241 | 79.852 | 1.00 | 36.04 | E | C |
| ATOM | 7136 | O | LEU | E | 348 | −21.156 | 44.246 | 79.730 | 1.00 | 36.05 | E | O |
| ATOM | 7137 | N | LYS | E | 349 | −22.890 | 43.170 | 80.679 | 1.00 | 38.09 | E | N |
| ATOM | 7138 | CA | LYS | E | 349 | −23.281 | 44.289 | 81.533 | 1.00 | 37.29 | E | C |
| ATOM | 7139 | CB | LYS | E | 349 | −22.064 | 44.785 | 82.327 | 1.00 | 40.99 | E | C |
| ATOM | 7140 | CG | LYS | E | 349 | −22.340 | 45.967 | 83.253 | 1.00 | 48.84 | E | C |
| ATOM | 7141 | CD | LYS | E | 349 | −21.568 | 47.225 | 82.821 | 1.00 | 52.75 | E | C |
| ATOM | 7142 | CE | LYS | E | 349 | −22.456 | 48.474 | 82.854 | 1.00 | 54.80 | E | C |
| ATOM | 7143 | NZ | LYS | E | 349 | −23.350 | 48.514 | 84.058 | 1.00 | 56.28 | E | N |
| ATOM | 7144 | C | LYS | E | 349 | −23.903 | 45.443 | 80.743 | 1.00 | 35.16 | E | C |
| ATOM | 7145 | O | LYS | E | 349 | −23.549 | 46.605 | 80.932 | 1.00 | 34.71 | E | O |
| ATOM | 7146 | N | LEU | E | 350 | −24.839 | 45.125 | 79.855 | 1.00 | 33.66 | E | N |
| ATOM | 7147 | CA | LEU | E | 350 | −25.488 | 46.166 | 79.070 | 1.00 | 31.32 | E | C |
| ATOM | 7148 | CB | LEU | E | 350 | −24.736 | 46.414 | 77.754 | 1.00 | 32.09 | E | C |
| ATOM | 7149 | CG | LEU | E | 350 | −23.263 | 46.038 | 77.610 | 1.00 | 33.37 | E | C |
| ATOM | 7150 | CD1 | LEU | E | 350 | −23.024 | 45.435 | 76.233 | 1.00 | 32.43 | E | C |
| ATOM | 7151 | CD2 | LEU | E | 350 | −22.402 | 47.279 | 77.808 | 1.00 | 32.13 | E | C |
| ATOM | 7152 | C | LEU | E | 350 | −26.920 | 45.827 | 78.727 | 1.00 | 29.74 | E | C |
| ATOM | 7153 | O | LEU | E | 350 | −27.301 | 44.661 | 78.686 | 1.00 | 30.86 | E | O |
| ATOM | 7154 | N | HIS | E | 351 | −27.720 | 46.863 | 78.507 | 1.00 | 30.20 | E | N |
| ATOM | 7155 | CA | HIS | E | 351 | −29.091 | 46.666 | 78.081 | 1.00 | 33.64 | E | C |
| ATOM | 7156 | CB | HIS | E | 351 | −30.111 | 47.228 | 79.066 | 1.00 | 35.43 | E | C |
| ATOM | 7157 | CG | HIS | E | 351 | −31.521 | 46.857 | 78.719 | 1.00 | 41.36 | E | C |
| ATOM | 7158 | CD2 | HIS | E | 351 | −32.358 | 47.337 | 77.767 | 1.00 | 42.81 | E | C |
| ATOM | 7159 | ND1 | HIS | E | 351 | −32.194 | 45.820 | 79.330 | 1.00 | 41.80 | E | N |
| ATOM | 7160 | CE1 | HIS | E | 351 | −33.383 | 45.676 | 78.771 | 1.00 | 42.52 | E | C |
| ATOM | 7161 | NE2 | HIS | E | 351 | −33.507 | 46.586 | 77.819 | 1.00 | 43.65 | E | N |
| ATOM | 7162 | C | HIS | E | 351 | −29.223 | 47.393 | 76.751 | 1.00 | 33.35 | E | C |
| ATOM | 7163 | O | HIS | E | 351 | −29.137 | 48.618 | 76.685 | 1.00 | 31.65 | E | O |
| ATOM | 7164 | N | PRO | E | 352 | −29.406 | 46.635 | 75.667 | 1.00 | 33.00 | E | N |
| ATOM | 7165 | CD | PRO | E | 352 | −29.479 | 45.166 | 75.646 | 1.00 | 33.14 | E | C |
| ATOM | 7166 | CA | PRO | E | 352 | −29.543 | 47.203 | 74.328 | 1.00 | 34.20 | E | C |
| ATOM | 7167 | CB | PRO | E | 352 | −30.278 | 46.112 | 73.542 | 1.00 | 34.92 | E | C |
| ATOM | 7168 | CG | PRO | E | 352 | −30.328 | 44.894 | 74.456 | 1.00 | 34.49 | E | C |
| ATOM | 7169 | C | PRO | E | 352 | −30.269 | 48.547 | 74.256 | 1.00 | 33.90 | E | C |
| ATOM | 7170 | O | PRO | E | 352 | −29.785 | 49.476 | 73.611 | 1.00 | 34.86 | E | O |
| ATOM | 7171 | N | TYR | E | 353 | −31.413 | 48.657 | 74.926 | 1.00 | 32.70 | E | N |
| ATOM | 7172 | CA | TYR | E | 353 | −32.203 | 49.886 | 74.882 | 1.00 | 32.69 | E | C |
| ATOM | 7173 | CB | TYR | E | 353 | −33.534 | 49.672 | 75.609 | 1.00 | 32.89 | E | C |
| ATOM | 7174 | CG | TYR | E | 353 | −34.402 | 48.612 | 74.961 | 1.00 | 33.18 | E | C |
| ATOM | 7175 | CD1 | TYR | E | 353 | −34.063 | 48.067 | 73.718 | 1.00 | 32.73 | E | C |
| ATOM | 7176 | CE1 | TYR | E | 353 | −34.838 | 47.077 | 73.124 | 1.00 | 32.46 | E | C |
| ATOM | 7177 | CD2 | TYR | E | 353 | −35.547 | 48.137 | 75.595 | 1.00 | 33.68 | E | C |
| ATOM | 7178 | CE2 | TYR | E | 353 | −36.335 | 47.141 | 75.010 | 1.00 | 35.69 | E | C |
| ATOM | 7179 | CZ | TYR | E | 353 | −35.974 | 46.615 | 73.776 | 1.00 | 35.02 | E | C |
| ATOM | 7180 | OH | TYR | E | 353 | −36.741 | 45.624 | 73.198 | 1.00 | 36.30 | E | O |
| ATOM | 7181 | C | TYR | E | 353 | −31.519 | 51.150 | 75.393 | 1.00 | 31.48 | E | C |
| ATOM | 7182 | O | TYR | E | 353 | −31.956 | 52.262 | 75.082 | 1.00 | 30.47 | E | O |
| ATOM | 7183 | N | ASP | E | 354 | −30.448 | 50.988 | 76.164 | 1.00 | 31.65 | E | N |
| ATOM | 7184 | CA | ASP | E | 354 | −29.706 | 52.139 | 76.683 | 1.00 | 29.56 | E | C |
| ATOM | 7185 | CB | ASP | E | 354 | −29.130 | 51.838 | 78.069 | 1.00 | 30.15 | E | C |
| ATOM | 7186 | CG | ASP | E | 354 | −30.203 | 51.599 | 79.106 | 1.00 | 32.88 | E | C |
| ATOM | 7187 | OD1 | ASP | E | 354 | −31.221 | 52.326 | 79.087 | 1.00 | 31.78 | E | O |
| ATOM | 7188 | OD2 | ASP | E | 354 | −30.027 | 50.682 | 79.936 | 1.00 | 34.21 | E | O |
| ATOM | 7189 | C | ASP | E | 354 | −28.564 | 52.485 | 75.739 | 1.00 | 26.22 | E | C |
| ATOM | 7190 | O | ASP | E | 354 | −27.894 | 53.503 | 75.911 | 1.00 | 27.33 | E | O |
| ATOM | 7191 | N | LEU | E | 355 | −28.343 | 51.626 | 74.747 | 1.00 | 24.22 | E | N |
| ATOM | 7192 | CA | LEU | E | 355 | −27.277 | 51.841 | 73.785 | 1.00 | 21.95 | E | C |
| ATOM | 7193 | CB | LEU | E | 355 | −27.178 | 50.658 | 72.830 | 1.00 | 21.82 | E | C |
| ATOM | 7194 | CG | LEU | E | 355 | −26.441 | 49.465 | 73.453 | 1.00 | 22.23 | E | C |
| ATOM | 7195 | CD1 | LEU | E | 355 | −26.249 | 48.389 | 72.407 | 1.00 | 22.04 | E | C |
| ATOM | 7196 | CD2 | LEU | E | 355 | −25.096 | 49.908 | 74.015 | 1.00 | 18.78 | E | C |
| ATOM | 7197 | C | LEU | E | 355 | −27.462 | 53.139 | 73.018 | 1.00 | 21.12 | E | C |
| ATOM | 7198 | O | LEU | E | 355 | −28.581 | 53.628 | 72.835 | 1.00 | 20.14 | E | O |
| ATOM | 7199 | N | THR | E | 356 | −26.339 | 53.682 | 72.568 | 1.00 | 18.55 | E | N |
| ATOM | 7200 | CA | THR | E | 356 | −26.293 | 54.950 | 71.862 | 1.00 | 17.94 | E | C |
| ATOM | 7201 | CB | THR | E | 356 | −25.978 | 56.036 | 72.903 | 1.00 | 18.62 | E | C |
| ATOM | 7202 | OG1 | THR | E | 356 | −27.200 | 56.585 | 73.399 | 1.00 | 19.89 | E | O |
| ATOM | 7203 | CG2 | THR | E | 356 | −25.116 | 57.112 | 72.338 | 1.00 | 20.48 | E | C |
| ATOM | 7204 | C | THR | E | 356 | −25.162 | 54.827 | 70.835 | 1.00 | 18.73 | E | C |
| ATOM | 7205 | O | THR | E | 356 | −24.393 | 53.869 | 70.901 | 1.00 | 21.45 | E | O |
| ATOM | 7206 | N | VAL | E | 357 | −25.043 | 55.742 | 69.873 | 1.00 | 16.87 | E | N |
| ATOM | 7207 | CA | VAL | E | 357 | −23.918 | 55.603 | 68.950 | 1.00 | 16.13 | E | C |
| ATOM | 7208 | CB | VAL | E | 357 | −23.983 | 56.566 | 67.708 | 1.00 | 15.62 | E | C |
| ATOM | 7209 | CG1 | VAL | E | 357 | −25.361 | 56.492 | 67.057 | 1.00 | 11.53 | E | C |
| ATOM | 7210 | CG2 | VAL | E | 357 | −23.621 | 57.976 | 68.100 | 1.00 | 15.64 | E | C |
| ATOM | 7211 | C | VAL | E | 357 | −22.639 | 55.865 | 69.750 | 1.00 | 15.59 | E | C |
| ATOM | 7212 | O | VAL | E | 357 | −21.577 | 55.359 | 69.408 | 1.00 | 15.47 | E | O |
| ATOM | 7213 | N | ASP | E | 358 | −22.753 | 56.636 | 70.831 | 1.00 | 16.04 | E | N |
| ATOM | 7214 | CA | ASP | E | 358 | −21.606 | 56.931 | 71.690 | 1.00 | 16.24 | E | C |
| ATOM | 7215 | CB | ASP | E | 358 | −21.976 | 57.932 | 72.786 | 1.00 | 20.37 | E | C |
| ATOM | 7216 | CG | ASP | E | 358 | −22.214 | 59.330 | 72.259 | 1.00 | 24.67 | E | C |
| ATOM | 7217 | OD1 | ASP | E | 358 | −21.646 | 59.683 | 71.196 | 1.00 | 25.93 | E | O |
| ATOM | 7218 | OD2 | ASP | E | 358 | −22.976 | 60.081 | 72.922 | 1.00 | 27.79 | E | O |
| ATOM | 7219 | C | ASP | E | 358 | −21.116 | 55.651 | 72.361 | 1.00 | 17.28 | E | C |
| ATOM | 7220 | O | ASP | E | 358 | −19.921 | 55.363 | 72.362 | 1.00 | 18.74 | E | O |
| ATOM | 7221 | N | SER | E | 359 | −22.044 | 54.890 | 72.942 | 1.00 | 18.28 | E | N |
| ATOM | 7222 | CA | SER | E | 359 | −21.699 | 53.640 | 73.622 | 1.00 | 17.51 | E | C |
| ATOM | 7223 | CB | SER | E | 359 | −22.838 | 53.201 | 74.549 | 1.00 | 15.56 | E | C |
| ATOM | 7224 | OG | SER | E | 359 | −24.102 | 53.357 | 73.934 | 1.00 | 17.84 | E | O |
| ATOM | 7225 | C | SER | E | 359 | −21.382 | 52.523 | 72.628 | 1.00 | 18.55 | E | C |
| ATOM | 7226 | O | SER | E | 359 | −20.621 | 51.603 | 72.933 | 1.00 | 16.78 | E | O |
| ATOM | 7227 | N | LEU | E | 360 | −21.973 | 52.603 | 71.441 | 1.00 | 18.38 | E | N |
| ATOM | 7228 | CA | LEU | E | 360 | −21.721 | 51.612 | 70.403 | 1.00 | 18.77 | E | C |
| ATOM | 7229 | CB | LEU | E | 360 | −22.634 | 51.862 | 69.208 | 1.00 | 19.60 | E | C |
| ATOM | 7230 | CG | LEU | E | 360 | −22.430 | 50.918 | 68.025 | 1.00 | 21.48 | E | C |
| ATOM | 7231 | CD1 | LEU | E | 360 | −22.716 | 49.475 | 68.445 | 1.00 | 20.62 | E | C |
| ATOM | 7232 | CD2 | LEU | E | 360 | −23.354 | 51.347 | 66.880 | 1.00 | 23.59 | E | C |
| ATOM | 7233 | C | LEU | E | 360 | −20.255 | 51.706 | 69.972 | 1.00 | 18.84 | E | C |
| ATOM | 7234 | O | LEU | E | 360 | −19.647 | 50.710 | 69.596 | 1.00 | 19.18 | E | O |
| ATOM | 7235 | N | ASP | E | 361 | −19.716 | 52.922 | 70.020 | 1.00 | 19.28 | E | N |
| ATOM | 7236 | CA | ASP | E | 361 | −18.319 | 53.211 | 69.693 | 1.00 | 24.43 | E | C |
| ATOM | 7237 | CB | ASP | E | 361 | −17.445 | 52.888 | 70.922 | 1.00 | 25.19 | E | C |
| ATOM | 7238 | CG | ASP | E | 361 | −16.287 | 53.858 | 71.101 | 1.00 | 27.16 | E | C |
| ATOM | 7239 | OD1 | ASP | E | 361 | −16.317 | 54.956 | 70.504 | 1.00 | 34.15 | E | O |
| ATOM | 7240 | OD2 | ASP | E | 361 | −15.344 | 53.522 | 71.842 | 1.00 | 26.97 | E | O |
| ATOM | 7241 | C | ASP | E | 361 | −17.723 | 52.524 | 68.450 | 1.00 | 24.95 | E | C |
| ATOM | 7242 | O | ASP | E | 361 | −16.604 | 52.007 | 68.513 | 1.00 | 26.89 | E | O |
| ATOM | 7243 | N | VAL | E | 362 | −18.437 | 52.533 | 67.323 | 1.00 | 25.31 | E | N |
| ATOM | 7244 | CA | VAL | E | 362 | −17.913 | 51.901 | 66.115 | 1.00 | 24.37 | E | C |
| ATOM | 7245 | CB | VAL | E | 362 | −19.002 | 51.115 | 65.358 | 1.00 | 23.24 | E | C |
| ATOM | 7246 | CG1 | VAL | E | 362 | −19.250 | 49.790 | 66.063 | 1.00 | 21.76 | E | C |
| ATOM | 7247 | CG2 | VAL | E | 362 | −20.280 | 51.928 | 65.277 | 1.00 | 22.98 | E | C |
| ATOM | 7248 | C | VAL | E | 362 | −17.275 | 52.910 | 65.164 | 1.00 | 24.76 | E | C |
| ATOM | 7249 | O | VAL | E | 362 | −16.577 | 52.530 | 64.222 | 1.00 | 26.61 | E | O |
| ATOM | 7250 | N | HIS | E | 363 | −17.508 | 54.192 | 65.423 | 1.00 | 24.55 | E | N |
| ATOM | 7251 | CA | HIS | E | 363 | −16.962 | 55.260 | 64.596 | 1.00 | 26.57 | E | C |
| ATOM | 7252 | CB | HIS | E | 363 | −17.760 | 56.541 | 64.814 | 1.00 | 25.53 | E | C |
| ATOM | 7253 | CG | HIS | E | 363 | −17.831 | 57.429 | 63.615 | 1.00 | 28.45 | E | C |
| ATOM | 7254 | CD2 | HIS | E | 363 | −18.618 | 57.378 | 62.514 | 1.00 | 28.81 | E | C |
| ATOM | 7255 | ND1 | HIS | E | 363 | −17.036 | 58.547 | 63.471 | 1.00 | 29.44 | E | N |
| ATOM | 7256 | CE1 | HIS | E | 363 | −17.330 | 59.146 | 62.331 | 1.00 | 28.77 | E | C |
| ATOM | 7257 | NE2 | HIS | E | 363 | −18.287 | 58.457 | 61.733 | 1.00 | 30.33 | E | N |
| ATOM | 7258 | C | HIS | E | 363 | −15.502 | 55.520 | 64.940 | 1.00 | 28.48 | E | C |
| ATOM | 7259 | O | HIS | E | 363 | −15.132 | 55.569 | 66.117 | 1.00 | 30.25 | E | O |
| ATOM | 7260 | N | ALA | E | 364 | −14.674 | 55.675 | 63.913 | 1.00 | 29.72 | E | N |
| ATOM | 7261 | CA | ALA | E | 364 | −13.252 | 55.931 | 64.112 | 1.00 | 34.28 | E | C |
| ATOM | 7262 | CB | ALA | E | 364 | −12.484 | 55.679 | 62.821 | 1.00 | 33.94 | E | C |
| ATOM | 7263 | C | ALA | E | 364 | −13.081 | 57.373 | 64.552 | 1.00 | 36.73 | E | C |
| ATOM | 7264 | O | ALA | E | 364 | −13.648 | 58.286 | 63.947 | 1.00 | 38.90 | E | O |
| ATOM | 7265 | N | GLY | E | 365 | −12.293 | 57.592 | 65.598 | 1.00 | 40.30 | E | N |
| ATOM | 7266 | CA | GLY | E | 365 | −12.120 | 58.956 | 66.087 | 1.00 | 42.58 | E | C |
| ATOM | 7267 | C | GLY | E | 365 | −10.859 | 59.591 | 65.547 | 1.00 | 42.35 | E | C |
| ATOM | 7268 | O | GLY | E | 365 | −10.543 | 59.395 | 64.379 | 1.00 | 46.17 | E | O |
| ATOM | 7269 | N | ARG | E | 366 | −10.158 | 60.382 | 66.376 | 1.00 | 41.41 | E | N |
| ATOM | 7270 | CA | ARG | E | 366 | −8.891 | 61.001 | 65.968 | 1.00 | 41.40 | E | C |
| ATOM | 7271 | CB | ARG | E | 366 | −8.499 | 62.170 | 66.863 | 1.00 | 40.45 | E | C |
| ATOM | 7272 | CG | ARG | E | 366 | −9.656 | 62.880 | 67.468 | 1.00 | 40.49 | E | C |
| ATOM | 7273 | CD | ARG | E | 366 | −9.669 | 64.304 | 66.978 | 1.00 | 38.20 | E | C |
| ATOM | 7274 | NE | ARG | E | 366 | −10.511 | 65.082 | 67.867 | 1.00 | 36.14 | E | N |
| ATOM | 7275 | CZ | ARG | E | 366 | −10.186 | 65.373 | 69.121 | 1.00 | 38.39 | E | C |
| ATOM | 7276 | NH1 | ARG | E | 366 | −9.027 | 64.948 | 69.633 | 1.00 | 39.88 | E | N |
| ATOM | 7277 | NH2 | ARG | E | 366 | −11.033 | 66.072 | 69.870 | 1.00 | 41.95 | E | N |
| ATOM | 7278 | C | ARG | E | 366 | −7.834 | 59.918 | 66.120 | 1.00 | 42.38 | E | C |
| ATOM | 7279 | O | ARG | E | 366 | −6.814 | 59.913 | 65.425 | 1.00 | 44.29 | E | O |
| ATOM | 7280 | N | GLN | E | 367 | −8.080 | 59.012 | 67.060 | 1.00 | 43.40 | E | N |
| ATOM | 7281 | CA | GLN | E | 367 | −7.183 | 57.882 | 67.320 | 1.00 | 44.54 | E | C |
| ATOM | 7282 | CB | GLN | E | 367 | −7.510 | 57.246 | 68.689 | 1.00 | 47.48 | E | C |
| ATOM | 7283 | CG | GLN | E | 367 | −7.735 | 55.722 | 68.699 | 1.00 | 50.56 | E | C |
| ATOM | 7284 | CD | GLN | E | 367 | −9.212 | 55.343 | 68.907 | 1.00 | 53.01 | E | C |
| ATOM | 7285 | OE1 | GLN | E | 367 | −10.023 | 56.157 | 69.364 | 1.00 | 55.49 | E | O |
| ATOM | 7286 | NE2 | GLN | E | 367 | −9.560 | 54.101 | 68.558 | 1.00 | 52.15 | E | N |
| ATOM | 7287 | C | GLN | E | 367 | −7.406 | 56.899 | 66.177 | 1.00 | 43.62 | E | C |
| ATOM | 7288 | O | GLN | E | 367 | −8.136 | 57.227 | 65.231 | 1.00 | 45.81 | E | O |
| ATOM | 7289 | N | THR | E | 368 | −6.810 | 55.707 | 66.244 | 1.00 | 39.32 | E | N |
| ATOM | 7290 | CA | THR | E | 368 | −6.944 | 54.722 | 65.158 | 1.00 | 38.04 | E | C |
| ATOM | 7291 | CB | THR | E | 368 | −8.426 | 54.507 | 64.657 | 1.00 | 36.47 | E | C |
| ATOM | 7292 | OG1 | THR | E | 368 | −8.778 | 55.537 | 63.711 | 1.00 | 32.16 | E | O |
| ATOM | 7293 | CG2 | THR | E | 368 | −9.427 | 54.496 | 65.847 | 1.00 | 37.91 | E | C |
| ATOM | 7294 | C | THR | E | 368 | −6.142 | 55.247 | 63.957 | 1.00 | 35.34 | E | C |
| ATOM | 7295 | O | THR | E | 368 | −5.737 | 54.483 | 63.064 | 1.00 | 32.08 | E | O |
| ATOM | 7296 | N | PHE | E | 369 | −5.951 | 56.564 | 63.934 | 1.00 | 32.08 | E | N |
| ATOM | 7297 | CA | PHE | E | 369 | −5.180 | 57.214 | 62.896 | 1.00 | 32.31 | E | C |
| ATOM | 7298 | CB | PHE | E | 369 | −5.188 | 58.732 | 63.101 | 1.00 | 29.97 | E | C |
| ATOM | 7299 | CG | PHE | E | 369 | −4.396 | 59.468 | 62.074 | 1.00 | 30.74 | E | C |
| ATOM | 7300 | CD1 | PHE | E | 369 | −4.927 | 59.719 | 60.809 | 1.00 | 32.40 | E | C |
| ATOM | 7301 | CD2 | PHE | E | 369 | −3.084 | 59.843 | 62.342 | 1.00 | 31.35 | E | C |
| ATOM | 7302 | CE1 | PHE | E | 369 | −4.155 | 60.329 | 59.818 | 1.00 | 32.87 | E | C |
| ATOM | 7303 | CE2 | PHE | E | 369 | −2.302 | 60.453 | 61.359 | 1.00 | 33.42 | E | C |
| ATOM | 7304 | CZ | PHE | E | 369 | −2.837 | 60.697 | 60.097 | 1.00 | 32.83 | E | C |
| ATOM | 7305 | C | PHE | E | 369 | −3.775 | 56.658 | 63.051 | 1.00 | 33.10 | E | C |
| ATOM | 7306 | O | PHE | E | 369 | −3.113 | 56.924 | 64.060 | 1.00 | 32.78 | E | O |
| ATOM | 7307 | N | GLN | E | 370 | −3.331 | 55.881 | 62.063 | 1.00 | 34.84 | E | N |
| ATOM | 7308 | CA | GLN | E | 370 | −2.018 | 55.252 | 62.122 | 1.00 | 33.40 | E | C |
| ATOM | 7309 | CB | GLN | E | 370 | −0.913 | 56.307 | 62.124 | 1.00 | 32.16 | E | C |
| ATOM | 7310 | CG | GLN | E | 370 | −0.418 | 56.586 | 60.720 | 1.00 | 33.37 | E | C |
| ATOM | 7311 | CD | GLN | E | 370 | 0.325 | 57.898 | 60.602 | 1.00 | 34.90 | E | C |
| ATOM | 7312 | OE1 | GLN | E | 370 | 0.115 | 58.826 | 61.398 | 1.00 | 37.50 | E | O |
| ATOM | 7313 | NE2 | GLN | E | 370 | 1.202 | 57.989 | 59.608 | 1.00 | 33.39 | E | N |
| ATOM | 7314 | C | GLN | E | 370 | −1.968 | 54.372 | 63.369 | 1.00 | 33.81 | E | C |
| ATOM | 7315 | O | GLN | E | 370 | −0.940 | 54.254 | 64.038 | 1.00 | 35.69 | E | O |
| ATOM | 7316 | N | ARG | E | 371 | −3.120 | 53.786 | 63.688 | 1.00 | 33.45 | E | N |
| ATOM | 7317 | CA | ARG | E | 371 | −3.263 | 52.846 | 64.799 | 1.00 | 32.46 | E | C |
| ATOM | 7318 | CB | ARG | E | 371 | −3.974 | 53.481 | 66.015 | 1.00 | 30.24 | E | C |
| ATOM | 7319 | CG | ARG | E | 371 | −3.141 | 54.518 | 66.795 | 1.00 | 33.27 | E | C |
| ATOM | 7320 | CD | ARG | E | 371 | −2.159 | 53.917 | 67.819 | 1.00 | 33.62 | E | C |
| ATOM | 7321 | NE | ARG | E | 371 | −2.489 | 52.558 | 68.270 | 1.00 | 33.83 | E | N |
| ATOM | 7322 | CZ | ARG | E | 371 | −2.961 | 52.258 | 69.486 | 1.00 | 33.46 | E | C |
| ATOM | 7323 | NH1 | ARG | E | 371 | −3.172 | 53.221 | 70.383 | 1.00 | 31.48 | E | N |
| ATOM | 7324 | NH2 | ARG | E | 371 | −3.186 | 50.990 | 69.828 | 1.00 | 29.84 | E | N |
| ATOM | 7325 | C | ARG | E | 371 | −4.164 | 51.792 | 64.162 | 1.00 | 31.64 | E | C |
| ATOM | 7326 | O | ARG | E | 371 | −5.366 | 51.751 | 64.428 | 1.00 | 30.41 | E | O |
| ATOM | 7327 | N | PHE | E | 372 | −3.594 | 50.965 | 63.285 | 1.00 | 29.99 | E | N |
| ATOM | 7328 | CA | PHE | E | 372 | −4.418 | 49.954 | 62.629 | 1.00 | 31.06 | E | C |
| ATOM | 7329 | CB | PHE | E | 372 | −3.603 | 49.123 | 61.642 | 1.00 | 29.56 | E | C |
| ATOM | 7330 | CG | PHE | E | 372 | −4.434 | 48.554 | 60.523 | 1.00 | 29.94 | E | C |
| ATOM | 7331 | CD1 | PHE | E | 372 | −4.736 | 49.334 | 59.401 | 1.00 | 28.50 | E | C |
| ATOM | 7332 | CD2 | PHE | E | 372 | −4.931 | 47.257 | 60.595 | 1.00 | 26.16 | E | C |
| ATOM | 7333 | CE1 | PHE | E | 372 | −5.527 | 48.827 | 58.371 | 1.00 | 27.10 | E | C |
| ATOM | 7334 | CE2 | PHE | E | 372 | −5.721 | 46.738 | 59.576 | 1.00 | 27.19 | E | C |
| ATOM | 7335 | CZ | PHE | E | 372 | −6.025 | 47.525 | 58.459 | 1.00 | 26.91 | E | C |
| ATOM | 7336 | C | PHE | E | 372 | −5.051 | 49.047 | 63.666 | 1.00 | 31.50 | E | C |
| ATOM | 7337 | O | PHE | E | 372 | −6.213 | 48.669 | 63.551 | 1.00 | 32.64 | E | O |
| ATOM | 7338 | N | ASP | E | 373 | −4.275 | 48.703 | 64.685 | 1.00 | 32.84 | E | N |
| ATOM | 7339 | CA | ASP | E | 373 | −4.736 | 47.856 | 65.778 | 1.00 | 33.71 | E | C |
| ATOM | 7340 | CB | ASP | E | 373 | −3.717 | 47.927 | 66.902 | 1.00 | 35.50 | E | C |
| ATOM | 7341 | CG | ASP | E | 373 | −3.360 | 49.360 | 67.231 | 1.00 | 39.04 | E | C |
| ATOM | 7342 | OD1 | ASP | E | 373 | −4.114 | 49.967 | 68.026 | 1.00 | 44.67 | E | O |
| ATOM | 7343 | OD2 | ASP | E | 373 | −2.362 | 49.886 | 66.679 | 1.00 | 39.85 | E | O |
| ATOM | 7344 | C | ASP | E | 373 | −6.090 | 48.356 | 66.301 | 1.00 | 33.87 | E | C |
| ATOM | 7345 | O | ASP | E | 373 | −7.014 | 47.564 | 66.539 | 1.00 | 33.10 | E | O |
| ATOM | 7346 | N | LYS | E | 374 | −6.194 | 49.675 | 66.487 | 1.00 | 32.72 | E | N |
| ATOM | 7347 | CA | LYS | E | 374 | −7.426 | 50.290 | 66.994 | 1.00 | 33.12 | E | C |
| ATOM | 7348 | CB | LYS | E | 374 | −7.168 | 51.729 | 67.456 | 1.00 | 34.58 | E | C |
| ATOM | 7349 | CG | LYS | E | 374 | −6.452 | 51.833 | 68.800 | 1.00 | 37.96 | E | C |
| ATOM | 7350 | CD | LYS | E | 374 | −7.164 | 52.801 | 69.741 | 1.00 | 37.52 | E | C |
| ATOM | 7351 | CE | LYS | E | 374 | −6.464 | 52.856 | 71.090 | 1.00 | 40.28 | E | C |
| ATOM | 7352 | NZ | LYS | E | 374 | −6.002 | 54.246 | 71.418 | 1.00 | 42.39 | E | N |
| ATOM | 7353 | C | LYS | E | 374 | −8.511 | 50.300 | 65.927 | 1.00 | 32.91 | E | C |
| ATOM | 7354 | O | LYS | E | 374 | −9.707 | 50.272 | 66.235 | 1.00 | 33.38 | E | O |
| ATOM | 7355 | N | PHE | E | 375 | −8.092 | 50.349 | 64.667 | 1.00 | 33.55 | E | N |
| ATOM | 7356 | CA | PHE | E | 375 | −9.051 | 50.353 | 63.568 | 1.00 | 32.20 | E | C |
| ATOM | 7357 | CB | PHE | E | 375 | −8.344 | 50.607 | 62.234 | 1.00 | 29.17 | E | C |
| ATOM | 7358 | CG | PHE | E | 375 | −9.155 | 50.190 | 61.044 | 1.00 | 29.02 | E | C |
| ATOM | 7359 | CD1 | PHE | E | 375 | −10.316 | 50.883 | 60.709 | 1.00 | 27.40 | E | C |
| ATOM | 7360 | CD2 | PHE | E | 375 | −8.810 | 49.060 | 60.310 | 1.00 | 28.24 | E | C |
| ATOM | 7361 | CE1 | PHE | E | 375 | −11.131 | 50.456 | 59.669 | 1.00 | 24.05 | E | C |
| ATOM | 7362 | CE2 | PHE | E | 375 | −9.619 | 48.620 | 59.264 | 1.00 | 26.43 | E | C |
| ATOM | 7363 | CZ | PHE | E | 375 | −10.785 | 49.319 | 58.947 | 1.00 | 28.96 | E | C |
| ATOM | 7364 | C | PHE | E | 375 | −9.786 | 49.004 | 63.516 | 1.00 | 30.28 | E | C |
| ATOM | 7365 | O | PHE | E | 375 | −11.018 | 48.952 | 63.432 | 1.00 | 27.35 | E | O |
| ATOM | 7366 | N | ASN | E | 376 | −9.023 | 47.915 | 63.564 | 1.00 | 30.64 | E | N |
| ATOM | 7367 | CA | ASN | E | 376 | −9.619 | 46.578 | 63.519 | 1.00 | 34.18 | E | C |
| ATOM | 7368 | CB | ASN | E | 376 | −8.531 | 45.504 | 63.375 | 1.00 | 34.63 | E | C |
| ATOM | 7369 | CG | ASN | E | 376 | −8.562 | 44.817 | 62.008 | 1.00 | 39.81 | E | C |
| ATOM | 7370 | OD1 | ASN | E | 376 | −9.545 | 44.145 | 61.644 | 1.00 | 42.53 | E | O |
| ATOM | 7371 | ND2 | ASN | E | 376 | −7.485 | 44.980 | 61.243 | 1.00 | 41.15 | E | N |
| ATOM | 7372 | C | ASN | E | 376 | −10.453 | 46.289 | 64.770 | 1.00 | 36.67 | E | C |
| ATOM | 7373 | O | ASN | E | 376 | −11.376 | 45.469 | 64.739 | 1.00 | 37.46 | E | O |
| ATOM | 7374 | N | ASP | E | 377 | −10.142 | 46.968 | 65.873 | 1.00 | 37.52 | E | N |
| ATOM | 7375 | CA | ASP | E | 377 | −10.895 | 46.725 | 67.092 | 1.00 | 39.36 | E | C |
| ATOM | 7376 | CB | ASP | E | 377 | −9.993 | 46.914 | 68.317 | 1.00 | 39.70 | E | C |
| ATOM | 7377 | CG | ASP | E | 377 | −9.521 | 45.576 | 68.870 | 1.00 | 44.65 | E | C |
| ATOM | 7378 | OD1 | ASP | E | 377 | −9.406 | 44.605 | 68.068 | 1.00 | 44.95 | E | O |
| ATOM | 7379 | OD2 | ASP | E | 377 | −9.268 | 45.474 | 70.093 | 1.00 | 49.23 | E | O |
| ATOM | 7380 | C | ASP | E | 377 | −12.150 | 47.581 | 67.153 | 1.00 | 43.33 | E | C |
| ATOM | 7381 | O | ASP | E | 377 | −12.961 | 47.491 | 68.085 | 1.00 | 40.95 | E | O |
| ATOM | 7382 | N | LYS | E | 378 | −12.331 | 48.397 | 66.122 | 1.00 | 45.74 | E | N |
| ATOM | 7383 | CA | LYS | E | 378 | −13.520 | 49.232 | 66.023 | 1.00 | 47.05 | E | C |
| ATOM | 7384 | CB | LYS | E | 378 | −13.280 | 50.376 | 65.032 | 1.00 | 48.79 | E | C |
| ATOM | 7385 | CG | LYS | E | 378 | −13.829 | 51.727 | 65.480 | 1.00 | 51.59 | E | C |
| ATOM | 7386 | CD | LYS | E | 378 | −12.875 | 52.431 | 66.448 | 1.00 | 54.06 | E | C |
| ATOM | 7387 | CE | LYS | E | 378 | −13.615 | 53.042 | 67.627 | 1.00 | 55.27 | E | C |
| ATOM | 7388 | NZ | LYS | E | 378 | −13.036 | 54.359 | 68.017 | 1.00 | 61.21 | E | N |
| ATOM | 7389 | C | LYS | E | 378 | −14.686 | 48.365 | 65.549 | 1.00 | 48.29 | E | C |
| ATOM | 7390 | O | LYS | E | 378 | −15.847 | 48.746 | 65.701 | 1.00 | 47.60 | E | O |
| ATOM | 7391 | N | TYR | E | 379 | −14.379 | 47.197 | 64.977 | 1.00 | 48.69 | E | N |
| ATOM | 7392 | CA | TYR | E | 379 | −15.421 | 46.300 | 64.484 | 1.00 | 47.83 | E | C |
| ATOM | 7393 | CB | TYR | E | 379 | −14.825 | 45.217 | 63.562 | 1.00 | 52.04 | E | C |
| ATOM | 7394 | CG | TYR | E | 379 | −14.459 | 45.696 | 62.172 | 1.00 | 57.15 | E | C |
| ATOM | 7395 | CD1 | TYR | E | 379 | −13.148 | 45.588 | 61.699 | 1.00 | 58.61 | E | C |
| ATOM | 7396 | CE1 | TYR | E | 379 | −12.802 | 46.054 | 60.421 | 1.00 | 59.29 | E | C |
| ATOM | 7397 | CD2 | TYR | E | 379 | −15.413 | 46.277 | 61.342 | 1.00 | 57.98 | E | C |
| ATOM | 7398 | CE2 | TYR | E | 379 | −15.082 | 46.742 | 60.073 | 1.00 | 58.73 | E | C |
| ATOM | 7399 | CZ | TYR | E | 379 | −13.781 | 46.629 | 59.617 | 1.00 | 58.44 | E | C |
| ATOM | 7400 | OH | TYR | E | 379 | −13.490 | 47.080 | 58.352 | 1.00 | 55.47 | E | O |
| ATOM | 7401 | C | TYR | E | 379 | −16.190 | 45.631 | 65.620 | 1.00 | 45.79 | E | C |
| ATOM | 7402 | O | TYR | E | 379 | −17.116 | 44.842 | 65.379 | 1.00 | 48.00 | E | O |
| ATOM | 7403 | N | ASN | E | 380 | −15.801 | 45.947 | 66.854 | 1.00 | 41.44 | E | N |
| ATOM | 7404 | CA | ASN | E | 380 | −16.439 | 45.398 | 68.045 | 1.00 | 34.63 | E | C |
| ATOM | 7405 | CB | ASN | E | 380 | −15.403 | 45.143 | 69.133 | 1.00 | 31.97 | E | C |
| ATOM | 7406 | CG | ASN | E | 380 | −14.339 | 44.165 | 68.693 | 1.00 | 29.74 | E | C |
| ATOM | 7407 | OD1 | ASN | E | 380 | −14.584 | 43.308 | 67.857 | 1.00 | 29.38 | E | O |
| ATOM | 7408 | ND2 | ASN | E | 380 | −13.155 | 44.280 | 69.278 | 1.00 | 27.94 | E | N |
| ATOM | 7409 | C | ASN | E | 380 | −17.483 | 46.373 | 68.578 | 1.00 | 32.90 | E | C |
| ATOM | 7410 | O | ASN | E | 380 | −17.146 | 47.354 | 69.235 | 1.00 | 31.25 | E | O |
| ATOM | 7411 | N | PRO | E | 381 | −18.770 | 46.119 | 68.279 | 1.00 | 29.21 | E | N |
| ATOM | 7412 | CD | PRO | E | 381 | −19.309 | 44.985 | 67.513 | 1.00 | 27.50 | E | C |
| ATOM | 7413 | CA | PRO | E | 381 | −19.824 | 47.013 | 68.767 | 1.00 | 27.40 | E | C |
| ATOM | 7414 | CB | PRO | E | 381 | −21.122 | 46.296 | 68.387 | 1.00 | 26.89 | E | C |
| ATOM | 7415 | CG | PRO | E | 381 | −20.738 | 45.345 | 67.295 | 1.00 | 26.03 | E | C |
| ATOM | 7416 | C | PRO | E | 381 | −19.689 | 47.127 | 70.284 | 1.00 | 26.52 | E | C |
| ATOM | 7417 | O | PRO | E | 381 | −19.435 | 46.129 | 70.960 | 1.00 | 26.46 | E | O |
| ATOM | 7418 | N | VAL | E | 382 | −19.834 | 48.327 | 70.825 | 1.00 | 27.34 | E | N |
| ATOM | 7419 | CA | VAL | E | 382 | −19.733 | 48.540 | 72.269 | 1.00 | 28.72 | E | C |
| ATOM | 7420 | CB | VAL | E | 382 | −21.057 | 48.091 | 72.982 | 1.00 | 27.46 | E | C |
| ATOM | 7421 | CG1 | VAL | E | 382 | −21.016 | 46.626 | 73.311 | 1.00 | 33.12 | E | C |
| ATOM | 7422 | CG2 | VAL | E | 382 | −21.276 | 48.898 | 74.244 | 1.00 | 28.17 | E | C |
| ATOM | 7423 | C | VAL | E | 382 | −18.506 | 47.873 | 72.920 | 1.00 | 26.79 | E | C |
| ATOM | 7424 | O | VAL | E | 382 | −18.534 | 47.496 | 74.094 | 1.00 | 26.51 | E | O |
| ATOM | 7425 | N | GLY | E | 383 | −17.432 | 47.736 | 72.144 | 1.00 | 24.54 | E | N |
| ATOM | 7426 | CA | GLY | E | 383 | −16.199 | 47.156 | 72.646 | 1.00 | 20.38 | E | C |
| ATOM | 7427 | C | GLY | E | 383 | −16.131 | 45.658 | 72.867 | 1.00 | 22.37 | E | C |
| ATOM | 7428 | O | GLY | E | 383 | −15.084 | 45.146 | 73.257 | 1.00 | 24.89 | E | O |
| ATOM | 7429 | N | ALA | E | 384 | −17.222 | 44.944 | 72.615 | 1.00 | 22.22 | E | N |
| ATOM | 7430 | CA | ALA | E | 384 | −17.245 | 43.501 | 72.827 | 1.00 | 19.99 | E | C |
| ATOM | 7431 | CB | ALA | E | 384 | −18.533 | 43.105 | 73.532 | 1.00 | 15.85 | E | C |
| ATOM | 7432 | C | ALA | E | 384 | −17.097 | 42.708 | 71.537 | 1.00 | 19.49 | E | C |
| ATOM | 7433 | O | ALA | E | 384 | −17.864 | 42.892 | 70.593 | 1.00 | 21.11 | E | O |
| ATOM | 7434 | N | SER | E | 385 | −16.117 | 41.815 | 71.506 | 1.00 | 20.15 | E | N |
| ATOM | 7435 | CA | SER | E | 385 | −15.887 | 40.982 | 70.338 | 1.00 | 21.28 | E | C |
| ATOM | 7436 | CB | SER | E | 385 | −14.560 | 40.230 | 70.477 | 1.00 | 21.70 | E | C |
| ATOM | 7437 | OG | SER | E | 385 | −14.633 | 39.221 | 71.470 | 1.00 | 28.89 | E | O |
| ATOM | 7438 | C | SER | E | 385 | −17.027 | 39.988 | 70.163 | 1.00 | 22.63 | E | C |
| ATOM | 7439 | O | SER | E | 385 | −17.311 | 39.548 | 69.052 | 1.00 | 24.60 | E | O |
| ATOM | 7440 | N | GLU | E | 386 | −17.680 | 39.633 | 71.267 | 1.00 | 25.53 | E | N |
| ATOM | 7441 | CA | GLU | E | 386 | −18.796 | 38.691 | 71.228 | 1.00 | 23.59 | E | C |
| ATOM | 7442 | CB | GLU | E | 386 | −19.346 | 38.446 | 72.636 | 1.00 | 24.69 | E | C |
| ATOM | 7443 | CG | GLU | E | 386 | −18.388 | 37.735 | 73.589 | 1.00 | 26.26 | E | C |
| ATOM | 7444 | CD | GLU | E | 386 | −17.538 | 38.696 | 74.405 | 1.00 | 27.41 | E | C |
| ATOM | 7445 | OE1 | GLU | E | 386 | −16.732 | 38.220 | 75.231 | 1.00 | 28.35 | E | O |
| ATOM | 7446 | OE2 | GLU | E | 386 | −17.674 | 39.925 | 74.222 | 1.00 | 28.13 | E | O |
| ATOM | 7447 | C | GLU | E | 386 | −19.900 | 39.262 | 70.355 | 1.00 | 25.54 | E | C |
| ATOM | 7448 | O | GLU | E | 386 | −20.576 | 38.527 | 69.636 | 1.00 | 27.16 | E | O |
| ATOM | 7449 | N | LEU | E | 387 | −20.081 | 40.578 | 70.421 | 1.00 | 24.67 | E | N |
| ATOM | 7450 | CA | LEU | E | 387 | −21.113 | 41.242 | 69.629 | 1.00 | 24.72 | E | C |
| ATOM | 7451 | CB | LEU | E | 387 | −21.344 | 42.653 | 70.155 | 1.00 | 23.79 | E | C |
| ATOM | 7452 | CG | LEU | E | 387 | −21.992 | 42.720 | 71.539 | 1.00 | 25.05 | E | C |
| ATOM | 7453 | CD1 | LEU | E | 387 | −22.269 | 44.166 | 71.887 | 1.00 | 24.26 | E | C |
| ATOM | 7454 | CD2 | LEU | E | 387 | −23.287 | 41.918 | 71.554 | 1.00 | 25.81 | E | C |
| ATOM | 7455 | C | LEU | E | 387 | −20.728 | 41.288 | 68.154 | 1.00 | 23.64 | E | C |
| ATOM | 7456 | O | LEU | E | 387 | −21.580 | 41.207 | 67.275 | 1.00 | 23.30 | E | O |
| ATOM | 7457 | N | ARG | E | 388 | −19.436 | 41.414 | 67.890 | 1.00 | 22.30 | E | N |
| ATOM | 7458 | CA | ARG | E | 388 | −18.944 | 41.442 | 66.524 | 1.00 | 23.44 | E | C |
| ATOM | 7459 | CB | ARG | E | 388 | −17.453 | 41.777 | 66.504 | 1.00 | 25.77 | E | C |
| ATOM | 7460 | CG | ARG | E | 388 | −16.740 | 41.377 | 65.223 | 1.00 | 30.71 | E | C |
| ATOM | 7461 | CD | ARG | E | 388 | −15.549 | 42.273 | 64.995 | 1.00 | 36.94 | E | C |
| ATOM | 7462 | NE | ARG | E | 388 | −14.842 | 41.953 | 63.752 | 1.00 | 45.20 | E | N |
| ATOM | 7463 | CZ | ARG | E | 388 | −13.577 | 42.301 | 63.515 | 1.00 | 47.98 | E | C |
| ATOM | 7464 | NH1 | ARG | E | 388 | −12.883 | 42.974 | 64.429 | 1.00 | 50.81 | E | N |
| ATOM | 7465 | NH2 | ARG | E | 388 | −13.007 | 41.984 | 62.362 | 1.00 | 50.47 | E | N |
| ATOM | 7466 | C | ARG | E | 388 | −19.166 | 40.080 | 65.871 | 1.00 | 23.21 | E | C |
| ATOM | 7467 | O | ARG | E | 388 | −19.604 | 39.999 | 64.725 | 1.00 | 24.44 | E | O |
| ATOM | 7468 | N | ASP | E | 389 | −18.855 | 39.015 | 66.603 | 1.00 | 20.68 | E | N |
| ATOM | 7469 | CA | ASP | E | 389 | −19.024 | 37.659 | 66.095 | 1.00 | 19.85 | E | C |
| ATOM | 7470 | CB | ASP | E | 389 | −18.470 | 36.641 | 67.087 | 1.00 | 23.68 | E | C |
| ATOM | 7471 | CG | ASP | E | 389 | −16.980 | 36.754 | 67.268 | 1.00 | 28.43 | E | C |
| ATOM | 7472 | OD1 | ASP | E | 389 | −16.424 | 35.952 | 68.049 | 1.00 | 30.11 | E | O |
| ATOM | 7473 | OD2 | ASP | E | 389 | −16.368 | 37.644 | 66.635 | 1.00 | 33.70 | E | O |
| ATOM | 7474 | C | ASP | E | 389 | −20.483 | 37.324 | 65.865 | 1.00 | 19.29 | E | C |
| ATOM | 7475 | O | ASP | E | 389 | −20.809 | 36.472 | 65.038 | 1.00 | 19.53 | E | O |
| ATOM | 7476 | N | LEU | E | 390 | −21.358 | 37.985 | 66.615 | 1.00 | 17.02 | E | N |
| ATOM | 7477 | CA | LEU | E | 390 | −22.784 | 37.727 | 66.520 | 1.00 | 17.20 | E | C |
| ATOM | 7478 | CB | LEU | E | 390 | −23.455 | 38.015 | 67.871 | 1.00 | 17.14 | E | C |
| ATOM | 7479 | CG | LEU | E | 390 | −24.990 | 37.971 | 67.933 | 1.00 | 19.67 | E | C |
| ATOM | 7480 | CD1 | LEU | E | 390 | −25.497 | 36.560 | 67.641 | 1.00 | 18.18 | E | C |
| ATOM | 7481 | CD2 | LEU | E | 390 | −25.450 | 38.411 | 69.305 | 1.00 | 19.33 | E | C |
| ATOM | 7482 | C | LEU | E | 390 | −23.488 | 38.510 | 65.424 | 1.00 | 15.63 | E | C |
| ATOM | 7483 | O | LEU | E | 390 | −24.297 | 37.955 | 64.685 | 1.00 | 15.26 | E | O |
| ATOM | 7484 | N | TYR | E | 391 | −23.168 | 39.794 | 65.309 | 1.00 | 15.35 | E | N |
| ATOM | 7485 | CA | TYR | E | 391 | −23.819 | 40.660 | 64.331 | 1.00 | 15.33 | E | C |
| ATOM | 7486 | CB | TYR | E | 391 | −24.152 | 42.010 | 64.983 | 1.00 | 15.47 | E | C |
| ATOM | 7487 | CG | TYR | E | 391 | −25.211 | 41.950 | 66.068 | 1.00 | 17.95 | E | C |
| ATOM | 7488 | CD1 | TYR | E | 391 | −26.569 | 41.882 | 65.745 | 1.00 | 17.46 | E | C |
| ATOM | 7489 | CE1 | TYR | E | 391 | −27.546 | 41.820 | 66.736 | 1.00 | 17.82 | E | C |
| ATOM | 7490 | CD2 | TYR | E | 391 | −24.856 | 41.959 | 67.418 | 1.00 | 18.11 | E | C |
| ATOM | 7491 | CE2 | TYR | E | 391 | −25.828 | 41.897 | 68.421 | 1.00 | 18.89 | E | C |
| ATOM | 7492 | CZ | TYR | E | 391 | −27.168 | 41.826 | 68.073 | 1.00 | 18.72 | E | C |
| ATOM | 7493 | OH | TYR | E | 391 | −28.125 | 41.742 | 69.058 | 1.00 | 15.44 | E | O |
| ATOM | 7494 | C | TYR | E | 391 | −23.069 | 40.932 | 63.026 | 1.00 | 15.89 | E | C |
| ATOM | 7495 | O | TYR | E | 391 | −23.687 | 41.323 | 62.030 | 1.00 | 11.87 | E | O |
| ATOM | 7496 | N | LEU | E | 392 | −21.753 | 40.733 | 63.017 | 1.00 | 14.05 | E | N |
| ATOM | 7497 | CA | LEU | E | 392 | −20.984 | 41.037 | 61.817 | 1.00 | 16.91 | E | C |
| ATOM | 7498 | CB | LEU | E | 392 | −20.110 | 42.274 | 62.059 | 1.00 | 15.38 | E | C |
| ATOM | 7499 | CG | LEU | E | 392 | −20.799 | 43.474 | 62.711 | 1.00 | 16.57 | E | C |
| ATOM | 7500 | CD1 | LEU | E | 392 | −19.761 | 44.488 | 63.126 | 1.00 | 16.62 | E | C |
| ATOM | 7501 | CD2 | LEU | E | 392 | −21.792 | 44.089 | 61.752 | 1.00 | 13.05 | E | C |
| ATOM | 7502 | C | LEU | E | 392 | −20.118 | 39.927 | 61.253 | 1.00 | 17.85 | E | C |
| ATOM | 7503 | O | LEU | E | 392 | −19.118 | 40.200 | 60.588 | 1.00 | 19.84 | E | O |
| ATOM | 7504 | N | LYS | E | 393 | −20.496 | 38.681 | 61.504 | 1.00 | 17.67 | E | N |
| ATOM | 7505 | CA | LYS | E | 393 | −19.734 | 37.552 | 60.993 | 1.00 | 19.50 | E | C |
| ATOM | 7506 | CB | LYS | E | 393 | −18.927 | 36.896 | 62.110 | 1.00 | 19.75 | E | C |
| ATOM | 7507 | CG | LYS | E | 393 | −17.776 | 37.753 | 62.588 | 1.00 | 21.05 | E | C |
| ATOM | 7508 | CD | LYS | E | 393 | −16.505 | 36.950 | 62.702 | 1.00 | 26.53 | E | C |
| ATOM | 7509 | CE | LYS | E | 393 | −15.424 | 37.740 | 63.416 | 1.00 | 28.73 | E | C |
| ATOM | 7510 | NZ | LYS | E | 393 | −14.233 | 36.888 | 63.675 | 1.00 | 32.09 | E | N |
| ATOM | 7511 | C | LYS | E | 393 | −20.685 | 36.550 | 60.378 | 1.00 | 17.81 | E | C |
| ATOM | 7512 | O | LYS | E | 393 | −21.868 | 36.534 | 60.706 | 1.00 | 18.57 | E | O |
| ATOM | 7513 | N | THR | E | 394 | −20.172 | 35.719 | 59.480 | 1.00 | 17.73 | E | N |
| ATOM | 7514 | CA | THR | E | 394 | −21.014 | 34.737 | 58.821 | 1.00 | 19.92 | E | C |
| ATOM | 7515 | CB | THR | E | 394 | −20.590 | 34.551 | 57.330 | 1.00 | 18.35 | E | C |
| ATOM | 7516 | OG1 | THR | E | 394 | −19.253 | 34.035 | 57.259 | 1.00 | 14.27 | E | O |
| ATOM | 7517 | CG2 | THR | E | 394 | −20.648 | 35.879 | 56.600 | 1.00 | 11.47 | E | C |
| ATOM | 7518 | C | THR | E | 394 | −21.025 | 33.387 | 59.544 | 1.00 | 22.07 | E | C |
| ATOM | 7519 | O | THR | E | 394 | −21.994 | 32.628 | 59.447 | 1.00 | 21.54 | E | O |
| ATOM | 7520 | N | ASP | E | 395 | −19.959 | 33.097 | 60.281 | 1.00 | 20.04 | E | N |
| ATOM | 7521 | CA | ASP | E | 395 | −19.881 | 31.839 | 60.998 | 1.00 | 24.78 | E | C |
| ATOM | 7522 | CB | ASP | E | 395 | −18.576 | 31.115 | 60.659 | 1.00 | 28.67 | E | C |
| ATOM | 7523 | CG | ASP | E | 395 | −18.569 | 29.668 | 61.135 | 1.00 | 34.32 | E | C |
| ATOM | 7524 | OD1 | ASP | E | 395 | −19.661 | 29.054 | 61.210 | 1.00 | 36.33 | E | O |
| ATOM | 7525 | OD2 | ASP | E | 395 | −17.469 | 29.148 | 61.434 | 1.00 | 36.05 | E | O |
| ATOM | 7526 | C | ASP | E | 395 | −19.979 | 32.024 | 62.503 | 1.00 | 24.10 | E | C |
| ATOM | 7527 | O | ASP | E | 395 | −19.072 | 32.557 | 63.131 | 1.00 | 23.72 | E | O |
| ATOM | 7528 | N | ASN | E | 396 | −21.091 | 31.583 | 63.079 | 1.00 | 25.29 | E | N |
| ATOM | 7529 | CA | ASN | E | 396 | −21.292 | 31.681 | 64.516 | 1.00 | 23.27 | E | C |
| ATOM | 7530 | CB | ASN | E | 396 | −21.652 | 33.114 | 64.920 | 1.00 | 21.37 | E | C |
| ATOM | 7531 | CG | ASN | E | 396 | −22.963 | 33.577 | 64.341 | 1.00 | 19.77 | E | C |
| ATOM | 7532 | OD1 | ASN | E | 396 | −23.229 | 34.776 | 64.288 | 1.00 | 24.36 | E | O |
| ATOM | 7533 | ND2 | ASN | E | 396 | −23.792 | 32.639 | 63.903 | 1.00 | 19.31 | E | N |
| ATOM | 7534 | C | ASN | E | 396 | −22.382 | 30.720 | 64.956 | 1.00 | 25.38 | E | C |
| ATOM | 7535 | O | ASN | E | 396 | −22.879 | 29.929 | 64.153 | 1.00 | 24.27 | E | O |
| ATOM | 7536 | N | TYR | E | 397 | −22.759 | 30.803 | 66.229 | 1.00 | 25.47 | E | N |
| ATOM | 7537 | CA | TYR | E | 397 | −23.775 | 29.923 | 66.773 | 1.00 | 24.85 | E | C |
| ATOM | 7538 | CB | TYR | E | 397 | −24.116 | 30.314 | 68.207 | 1.00 | 26.51 | E | C |
| ATOM | 7539 | CG | TYR | E | 397 | −24.917 | 29.247 | 68.906 | 1.00 | 26.74 | E | C |
| ATOM | 7540 | CD1 | TYR | E | 397 | −26.310 | 29.323 | 68.976 | 1.00 | 25.58 | E | C |
| ATOM | 7541 | CE1 | TYR | E | 397 | −27.056 | 28.318 | 69.581 | 1.00 | 27.54 | E | C |
| ATOM | 7542 | CD2 | TYR | E | 397 | −24.285 | 28.137 | 69.463 | 1.00 | 29.15 | E | C |
| ATOM | 7543 | CE2 | TYR | E | 397 | −25.022 | 27.123 | 70.073 | 1.00 | 31.77 | E | C |
| ATOM | 7544 | CZ | TYR | E | 397 | −26.407 | 27.221 | 70.126 | 1.00 | 32.32 | E | C |
| ATOM | 7545 | OH | TYR | E | 397 | −27.138 | 26.217 | 70.725 | 1.00 | 37.96 | E | O |
| ATOM | 7546 | C | TYR | E | 397 | −25.052 | 29.888 | 65.950 | 1.00 | 24.04 | E | C |
| ATOM | 7547 | O | TYR | E | 397 | −25.673 | 28.833 | 65.817 | 1.00 | 25.46 | E | O |
| ATOM | 7548 | N | ILE | E | 398 | −25.449 | 31.031 | 65.403 | 1.00 | 23.01 | E | N |
| ATOM | 7549 | CA | ILE | E | 398 | −26.666 | 31.082 | 64.600 | 1.00 | 21.31 | E | C |
| ATOM | 7550 | CB | ILE | E | 398 | −27.558 | 32.275 | 65.002 | 1.00 | 20.70 | E | C |
| ATOM | 7551 | CG2 | ILE | E | 398 | −28.110 | 32.052 | 66.393 | 1.00 | 23.92 | E | C |
| ATOM | 7552 | CG1 | ILE | E | 398 | −26.758 | 33.575 | 64.996 | 1.00 | 20.91 | E | C |
| ATOM | 7553 | CD1 | ILE | E | 398 | −27.638 | 34.803 | 65.037 | 1.00 | 19.67 | E | C |
| ATOM | 7554 | C | ILE | E | 398 | −26.382 | 31.141 | 63.104 | 1.00 | 21.82 | E | C |
| ATOM | 7555 | O | ILE | E | 398 | −27.215 | 31.587 | 62.321 | 1.00 | 21.07 | E | O |
| ATOM | 7556 | N | ASN | E | 399 | −25.197 | 30.685 | 62.711 | 1.00 | 23.35 | E | N |
| ATOM | 7557 | CA | ASN | E | 399 | −24.804 | 30.666 | 61.307 | 1.00 | 22.51 | E | C |
| ATOM | 7558 | CB | ASN | E | 399 | −25.684 | 29.676 | 60.549 | 1.00 | 24.45 | E | C |
| ATOM | 7559 | CG | ASN | E | 399 | −25.681 | 28.291 | 61.177 | 1.00 | 28.63 | E | C |
| ATOM | 7560 | OD1 | ASN | E | 399 | −24.621 | 27.716 | 61.431 | 1.00 | 28.79 | E | O |
| ATOM | 7561 | ND2 | ASN | E | 399 | −26.870 | 27.748 | 61.428 | 1.00 | 27.35 | E | N |
| ATOM | 7562 | C | ASN | E | 399 | −24.866 | 32.035 | 60.625 | 1.00 | 22.91 | E | C |
| ATOM | 7563 | O | ASN | E | 399 | −25.431 | 32.166 | 59.542 | 1.00 | 25.00 | E | O |
| ATOM | 7564 | N | GLY | E | 400 | −24.288 | 33.049 | 61.261 | 1.00 | 21.48 | E | N |
| ATOM | 7565 | CA | GLY | E | 400 | −24.277 | 34.386 | 60.693 | 1.00 | 18.50 | E | C |
| ATOM | 7566 | C | GLY | E | 400 | −25.602 | 34.886 | 60.149 | 1.00 | 19.26 | E | C |
| ATOM | 7567 | O | GLY | E | 400 | −25.632 | 35.676 | 59.208 | 1.00 | 18.66 | E | O |
| ATOM | 7568 | N | GLU | E | 401 | −26.702 | 34.448 | 60.743 | 1.00 | 18.19 | E | N |
| ATOM | 7569 | CA | GLU | E | 401 | −28.018 | 34.867 | 60.289 | 1.00 | 19.96 | E | C |
| ATOM | 7570 | CB | GLU | E | 401 | −29.092 | 34.083 | 61.031 | 1.00 | 20.31 | E | C |
| ATOM | 7571 | CG | GLU | E | 401 | −30.467 | 34.672 | 60.869 | 1.00 | 26.61 | E | C |
| ATOM | 7572 | CD | GLU | E | 401 | −31.522 | 33.856 | 61.580 | 1.00 | 31.69 | E | C |
| ATOM | 7573 | OE1 | GLU | E | 401 | −31.458 | 32.604 | 61.481 | 1.00 | 30.51 | E | O |
| ATOM | 7574 | OE2 | GLU | E | 401 | −32.404 | 34.469 | 62.231 | 1.00 | 30.19 | E | O |
| ATOM | 7575 | C | GLU | E | 401 | −28.282 | 36.368 | 60.450 | 1.00 | 21.50 | E | C |
| ATOM | 7576 | O | GLU | E | 401 | −28.947 | 36.985 | 59.614 | 1.00 | 21.08 | E | O |
| ATOM | 7577 | N | TYR | E | 402 | −27.770 | 36.951 | 61.528 | 1.00 | 21.66 | E | N |
| ATOM | 7578 | CA | TYR | E | 402 | −27.959 | 38.376 | 61.799 | 1.00 | 20.04 | E | C |
| ATOM | 7579 | CB | TYR | E | 402 | −27.461 | 38.706 | 63.208 | 1.00 | 22.68 | E | C |
| ATOM | 7580 | CG | TYR | E | 402 | −28.430 | 38.361 | 64.328 | 1.00 | 23.39 | E | C |
| ATOM | 7581 | CD1 | TYR | E | 402 | −29.676 | 37.800 | 64.058 | 1.00 | 22.54 | E | C |
| ATOM | 7582 | CE1 | TYR | E | 402 | −30.581 | 37.530 | 65.084 | 1.00 | 25.16 | E | C |
| ATOM | 7583 | CD2 | TYR | E | 402 | −28.109 | 38.637 | 65.659 | 1.00 | 21.96 | E | C |
| ATOM | 7584 | CE2 | TYR | E | 402 | −29.006 | 38.371 | 66.690 | 1.00 | 21.83 | E | C |
| ATOM | 7585 | CZ | TYR | E | 402 | −30.242 | 37.821 | 66.398 | 1.00 | 23.42 | E | C |
| ATOM | 7586 | OH | TYR | E | 402 | −31.152 | 37.590 | 67.407 | 1.00 | 17.75 | E | O |
| ATOM | 7587 | C | TYR | E | 402 | −27.232 | 39.253 | 60.781 | 1.00 | 17.85 | E | C |
| ATOM | 7588 | O | TYR | E | 402 | −27.758 | 40.268 | 60.341 | 1.00 | 17.61 | E | O |
| ATOM | 7589 | N | PHE | E | 403 | −26.017 | 38.855 | 60.423 | 1.00 | 16.98 | E | N |
| ATOM | 7590 | CA | PHE | E | 403 | −25.207 | 39.581 | 59.450 | 1.00 | 17.62 | E | C |
| ATOM | 7591 | CB | PHE | E | 403 | −23.844 | 38.905 | 59.308 | 1.00 | 17.22 | E | C |
| ATOM | 7592 | CG | PHE | E | 403 | −22.841 | 39.705 | 58.535 | 1.00 | 17.31 | E | C |
| ATOM | 7593 | CD1 | PHE | E | 403 | −22.902 | 41.094 | 58.517 | 1.00 | 17.14 | E | C |
| ATOM | 7594 | CD2 | PHE | E | 403 | −21.822 | 39.066 | 57.833 | 1.00 | 15.60 | E | C |
| ATOM | 7595 | CE1 | PHE | E | 403 | −21.960 | 41.835 | 57.812 | 1.00 | 17.20 | E | C |
| ATOM | 7596 | CE2 | PHE | E | 403 | −20.878 | 39.796 | 57.126 | 1.00 | 14.37 | E | C |
| ATOM | 7597 | CZ | PHE | E | 403 | −20.945 | 41.182 | 57.113 | 1.00 | 17.00 | E | C |
| ATOM | 7598 | C | PHE | E | 403 | −25.924 | 39.569 | 58.110 | 1.00 | 17.09 | E | C |
| ATOM | 7599 | O | PHE | E | 403 | −25.976 | 40.577 | 57.413 | 1.00 | 18.53 | E | O |
| ATOM | 7600 | N | ALA | E | 404 | −26.475 | 38.415 | 57.755 | 1.00 | 18.16 | E | N |
| ATOM | 7601 | CA | ALA | E | 404 | −27.208 | 38.269 | 56.505 | 1.00 | 18.24 | E | C |
| ATOM | 7602 | CB | ALA | E | 404 | −27.678 | 36.829 | 56.337 | 1.00 | 17.38 | E | C |
| ATOM | 7603 | C | ALA | E | 404 | −28.405 | 39.208 | 56.487 | 1.00 | 18.07 | E | C |
| ATOM | 7604 | O | ALA | E | 404 | −28.646 | 39.902 | 55.504 | 1.00 | 21.26 | E | O |
| ATOM | 7605 | N | THR | E | 405 | −29.150 | 39.242 | 57.583 | 1.00 | 18.57 | E | N |
| ATOM | 7606 | CA | THR | E | 405 | −30.321 | 40.100 | 57.657 | 1.00 | 18.12 | E | C |
| ATOM | 7607 | CB | THR | E | 405 | −31.081 | 39.888 | 58.976 | 1.00 | 15.79 | E | C |
| ATOM | 7608 | OG1 | THR | E | 405 | −31.343 | 38.490 | 59.146 | 1.00 | 15.69 | E | O |
| ATOM | 7609 | CG2 | THR | E | 405 | −32.401 | 40.636 | 58.957 | 1.00 | 7.68 | E | C |
| ATOM | 7610 | C | THR | E | 405 | −29.984 | 41.575 | 57.503 | 1.00 | 19.25 | E | C |
| ATOM | 7611 | O | THR | E | 405 | −30.708 | 42.311 | 56.829 | 1.00 | 22.15 | E | O |
| ATOM | 7612 | N | ILE | E | 406 | −28.892 | 42.012 | 58.124 | 1.00 | 21.49 | E | N |
| ATOM | 7613 | CA | ILE | E | 406 | −28.474 | 43.413 | 58.032 | 1.00 | 21.79 | E | C |
| ATOM | 7614 | CB | ILE | E | 406 | −27.226 | 43.707 | 58.895 | 1.00 | 20.75 | E | C |
| ATOM | 7615 | CG2 | ILE | E | 406 | −26.780 | 45.153 | 58.688 | 1.00 | 20.67 | E | C |
| ATOM | 7616 | CG1 | ILE | E | 406 | −27.542 | 43.468 | 60.375 | 1.00 | 20.67 | E | C |
| ATOM | 7617 | CD1 | ILE | E | 406 | −26.327 | 43.513 | 61.287 | 1.00 | 15.57 | E | C |
| ATOM | 7618 | C | ILE | E | 406 | −28.119 | 43.719 | 56.588 | 1.00 | 23.24 | E | C |
| ATOM | 7619 | O | ILE | E | 406 | −28.605 | 44.695 | 56.005 | 1.00 | 23.48 | E | O |
| ATOM | 7620 | N | ILE | E | 407 | −27.273 | 42.862 | 56.018 | 1.00 | 22.40 | E | N |
| ATOM | 7621 | CA | ILE | E | 407 | −26.820 | 43.005 | 54.639 | 1.00 | 18.62 | E | C |
| ATOM | 7622 | CB | ILE | E | 407 | −25.880 | 41.857 | 54.252 | 1.00 | 16.69 | E | C |
| ATOM | 7623 | CG2 | ILE | E | 407 | −25.957 | 41.595 | 52.763 | 1.00 | 16.72 | E | C |
| ATOM | 7624 | CG1 | ILE | E | 407 | −24.450 | 42.214 | 54.656 | 1.00 | 14.90 | E | C |
| ATOM | 7625 | CD1 | ILE | E | 407 | −23.513 | 41.042 | 54.663 | 1.00 | 15.29 | E | C |
| ATOM | 7626 | C | ILE | E | 407 | −27.974 | 43.059 | 53.652 | 1.00 | 20.43 | E | C |
| ATOM | 7627 | O | ILE | E | 407 | −27.924 | 43.812 | 52.685 | 1.00 | 21.49 | E | O |
| ATOM | 7628 | N | LYS | E | 408 | −29.014 | 42.268 | 53.888 | 1.00 | 20.58 | E | N |
| ATOM | 7629 | CA | LYS | E | 408 | −30.160 | 42.273 | 52.985 | 1.00 | 19.83 | E | C |
| ATOM | 7630 | CB | LYS | E | 408 | −31.057 | 41.065 | 53.244 | 1.00 | 18.68 | E | C |
| ATOM | 7631 | CG | LYS | E | 408 | −30.538 | 39.778 | 52.631 | 1.00 | 16.75 | E | C |
| ATOM | 7632 | CD | LYS | E | 408 | −30.799 | 38.598 | 53.539 | 1.00 | 22.05 | E | C |
| ATOM | 7633 | CE | LYS | E | 408 | −32.109 | 37.913 | 53.201 | 1.00 | 24.89 | E | C |
| ATOM | 7634 | NZ | LYS | E | 408 | −32.453 | 38.037 | 51.747 | 1.00 | 30.22 | E | N |
| ATOM | 7635 | C | LYS | E | 408 | −30.951 | 43.560 | 53.157 | 1.00 | 20.54 | E | C |
| ATOM | 7636 | O | LYS | E | 408 | −31.636 | 44.007 | 52.238 | 1.00 | 21.21 | E | O |
| ATOM | 7637 | N | GLU | E | 409 | −30.843 | 44.166 | 54.335 | 1.00 | 19.50 | E | N |
| ATOM | 7638 | CA | GLU | E | 409 | −31.554 | 45.409 | 54.595 | 1.00 | 20.35 | E | C |
| ATOM | 7639 | CB | GLU | E | 409 | −31.630 | 45.676 | 56.101 | 1.00 | 20.57 | E | C |
| ATOM | 7640 | CG | GLU | E | 409 | −32.838 | 45.039 | 56.766 | 1.00 | 20.72 | E | C |
| ATOM | 7641 | CD | GLU | E | 409 | −32.854 | 45.198 | 58.284 | 1.00 | 23.26 | E | C |
| ATOM | 7642 | OE1 | GLU | E | 409 | −31.939 | 45.837 | 58.847 | 1.00 | 22.14 | E | O |
| ATOM | 7643 | OE2 | GLU | E | 409 | −33.794 | 44.678 | 58.915 | 1.00 | 22.92 | E | O |
| ATOM | 7644 | C | GLU | E | 409 | −30.842 | 46.557 | 53.883 | 1.00 | 19.85 | E | C |
| ATOM | 7645 | O | GLU | E | 409 | −31.471 | 47.524 | 53.447 | 1.00 | 20.01 | E | O |
| ATOM | 7646 | N | VAL | E | 410 | −29.526 | 46.437 | 53.765 | 1.00 | 18.60 | E | N |
| ATOM | 7647 | CA | VAL | E | 410 | −28.715 | 47.445 | 53.087 | 1.00 | 18.31 | E | C |
| ATOM | 7648 | CB | VAL | E | 410 | −27.207 | 47.209 | 53.343 | 1.00 | 18.95 | E | C |
| ATOM | 7649 | CG1 | VAL | E | 410 | −26.376 | 48.138 | 52.466 | 1.00 | 18.62 | E | C |
| ATOM | 7650 | CG2 | VAL | E | 410 | −26.883 | 47.423 | 54.813 | 1.00 | 12.64 | E | C |
| ATOM | 7651 | C | VAL | E | 410 | −28.970 | 47.367 | 51.579 | 1.00 | 19.03 | E | C |
| ATOM | 7652 | O | VAL | E | 410 | −29.186 | 48.382 | 50.920 | 1.00 | 18.25 | E | O |
| ATOM | 7653 | N | GLY | E | 411 | −28.939 | 46.150 | 51.046 | 1.00 | 19.90 | E | N |
| ATOM | 7654 | CA | GLY | E | 411 | −29.178 | 45.949 | 49.631 | 1.00 | 18.74 | E | C |
| ATOM | 7655 | C | GLY | E | 411 | −30.534 | 46.490 | 49.223 | 1.00 | 19.89 | E | C |
| ATOM | 7656 | O | GLY | E | 411 | −30.685 | 47.061 | 48.145 | 1.00 | 22.56 | E | O |
| ATOM | 7657 | N | ALA | E | 412 | −31.528 | 46.318 | 50.082 | 1.00 | 20.29 | E | N |
| ATOM | 7658 | CA | ALA | E | 412 | −32.866 | 46.803 | 49.783 | 1.00 | 18.63 | E | C |
| ATOM | 7659 | CB | ALA | E | 412 | −33.848 | 46.299 | 50.817 | 1.00 | 17.59 | E | C |
| ATOM | 7660 | C | ALA | E | 412 | −32.887 | 48.320 | 49.744 | 1.00 | 21.32 | E | C |
| ATOM | 7661 | O | ALA | E | 412 | −33.653 | 48.915 | 48.988 | 1.00 | 21.87 | E | O |
| ATOM | 7662 | N | ASP | E | 413 | −32.052 | 48.955 | 50.563 | 1.00 | 21.76 | E | N |
| ATOM | 7663 | CA | ASP | E | 413 | −32.005 | 50.414 | 50.587 | 1.00 | 21.17 | E | C |
| ATOM | 7664 | CB | ASP | E | 413 | −31.135 | 50.907 | 51.746 | 1.00 | 24.18 | E | C |
| ATOM | 7665 | CG | ASP | E | 413 | −31.913 | 51.052 | 53.052 | 1.00 | 27.12 | E | C |
| ATOM | 7666 | OD1 | ASP | E | 413 | −31.278 | 51.000 | 54.132 | 1.00 | 23.75 | E | O |
| ATOM | 7667 | OD2 | ASP | E | 413 | −33.153 | 51.218 | 53.002 | 1.00 | 26.66 | E | O |
| ATOM | 7668 | C | ASP | E | 413 | −31.429 | 50.918 | 49.268 | 1.00 | 20.83 | E | C |
| ATOM | 7669 | O | ASP | E | 413 | −31.841 | 51.956 | 48.751 | 1.00 | 20.32 | E | O |
| ATOM | 7670 | N | LEU | E | 414 | −30.464 | 50.171 | 48.742 | 1.00 | 20.28 | E | N |
| ATOM | 7671 | CA | LEU | E | 414 | −29.798 | 50.498 | 47.488 | 1.00 | 18.16 | E | C |
| ATOM | 7672 | CB | LEU | E | 414 | −28.675 | 49.492 | 47.226 | 1.00 | 17.29 | E | C |
| ATOM | 7673 | CG | LEU | E | 414 | −27.231 | 49.858 | 47.582 | 1.00 | 18.57 | E | C |
| ATOM | 7674 | CD1 | LEU | E | 414 | −27.194 | 51.026 | 48.527 | 1.00 | 16.05 | E | C |
| ATOM | 7675 | CD2 | LEU | E | 414 | −26.549 | 48.652 | 48.190 | 1.00 | 16.41 | E | C |
| ATOM | 7676 | C | LEU | E | 414 | −30.801 | 50.459 | 46.338 | 1.00 | 18.61 | E | C |
| ATOM | 7677 | O | LEU | E | 414 | −30.892 | 51.401 | 45.551 | 1.00 | 16.77 | E | O |
| ATOM | 7678 | N | VAL | E | 415 | −31.552 | 49.363 | 46.259 | 1.00 | 19.90 | E | N |
| ATOM | 7679 | CA | VAL | E | 415 | −32.558 | 49.178 | 45.220 | 1.00 | 21.23 | E | C |
| ATOM | 7680 | CB | VAL | E | 415 | −33.314 | 47.849 | 45.406 | 1.00 | 22.07 | E | C |
| ATOM | 7681 | CG1 | VAL | E | 415 | −34.526 | 47.806 | 44.491 | 1.00 | 21.18 | E | C |
| ATOM | 7682 | CG2 | VAL | E | 415 | −32.389 | 46.675 | 45.106 | 1.00 | 19.05 | E | C |
| ATOM | 7683 | C | VAL | E | 415 | −33.574 | 50.307 | 45.220 | 1.00 | 22.59 | E | C |
| ATOM | 7684 | O | VAL | E | 415 | −34.149 | 50.637 | 44.186 | 1.00 | 24.88 | E | O |
| ATOM | 7685 | N | ASP | E | 416 | −33.796 | 50.894 | 46.388 | 1.00 | 26.28 | E | N |
| ATOM | 7686 | CA | ASP | E | 416 | −34.745 | 51.996 | 46.526 | 1.00 | 27.99 | E | C |
| ATOM | 7687 | CB | ASP | E | 416 | −35.053 | 52.255 | 47.999 | 1.00 | 32.99 | E | C |
| ATOM | 7688 | CG | ASP | E | 416 | −36.242 | 51.471 | 48.488 | 1.00 | 41.21 | E | C |
| ATOM | 7689 | OD1 | ASP | E | 416 | −36.612 | 51.647 | 49.668 | 1.00 | 47.22 | E | O |
| ATOM | 7690 | OD2 | ASP | E | 416 | −36.808 | 50.678 | 47.698 | 1.00 | 48.07 | E | O |
| ATOM | 7691 | C | ASP | E | 416 | −34.178 | 53.264 | 45.920 | 1.00 | 25.90 | E | C |
| ATOM | 7692 | O | ASP | E | 416 | −34.876 | 53.990 | 45.221 | 1.00 | 27.11 | E | O |
| ATOM | 7693 | N | ALA | E | 417 | −32.910 | 53.531 | 46.213 | 1.00 | 24.03 | E | N |
| ATOM | 7694 | CA | ALA | E | 417 | −32.228 | 54.716 | 45.711 | 1.00 | 22.92 | E | C |
| ATOM | 7695 | CB | ALA | E | 417 | −30.953 | 54.949 | 46.493 | 1.00 | 24.83 | E | C |
| ATOM | 7696 | C | ALA | E | 417 | −31.915 | 54.534 | 44.232 | 1.00 | 23.35 | E | C |
| ATOM | 7697 | O | ALA | E | 417 | −31.571 | 55.486 | 43.534 | 1.00 | 21.90 | E | O |
| ATOM | 7698 | N | LYS | E | 418 | −32.008 | 53.289 | 43.778 | 1.00 | 22.17 | E | N |
| ATOM | 7699 | CA | LYS | E | 418 | −31.795 | 52.929 | 42.378 | 1.00 | 19.87 | E | C |
| ATOM | 7700 | CB | LYS | E | 418 | −32.857 | 53.621 | 41.517 | 1.00 | 19.81 | E | C |
| ATOM | 7701 | CG | LYS | E | 418 | −32.740 | 53.325 | 40.027 | 1.00 | 20.80 | E | C |
| ATOM | 7702 | CD | LYS | E | 418 | −33.976 | 53.809 | 39.269 | 1.00 | 25.35 | E | C |
| ATOM | 7703 | CE | LYS | E | 418 | −33.962 | 53.357 | 37.808 | 1.00 | 25.69 | E | C |
| ATOM | 7704 | NZ | LYS | E | 418 | −34.644 | 54.345 | 36.909 | 1.00 | 27.32 | E | N |
| ATOM | 7705 | C | LYS | E | 418 | −30.441 | 53.126 | 41.704 | 1.00 | 17.42 | E | C |
| ATOM | 7706 | O | LYS | E | 418 | −29.956 | 52.210 | 41.049 | 1.00 | 18.26 | E | O |
| ATOM | 7707 | N | TYR | E | 419 | −29.826 | 54.296 | 41.859 | 1.00 | 17.92 | E | N |
| ATOM | 7708 | CA | TYR | E | 419 | −28.571 | 54.584 | 41.160 | 1.00 | 15.60 | E | C |
| ATOM | 7709 | CB | TYR | E | 419 | −28.573 | 56.056 | 40.741 | 1.00 | 14.27 | E | C |
| ATOM | 7710 | CG | TYR | E | 419 | −29.804 | 56.415 | 39.933 | 1.00 | 15.73 | E | C |
| ATOM | 7711 | CD1 | TYR | E | 419 | −29.931 | 55.999 | 38.613 | 1.00 | 16.42 | E | C |
| ATOM | 7712 | CE1 | TYR | E | 419 | −31.091 | 56.247 | 37.885 | 1.00 | 17.91 | E | C |
| ATOM | 7713 | CD2 | TYR | E | 419 | −30.871 | 57.102 | 40.507 | 1.00 | 16.50 | E | C |
| ATOM | 7714 | CE2 | TYR | E | 419 | −32.047 | 57.358 | 39.779 | 1.00 | 16.56 | E | C |
| ATOM | 7715 | CZ | TYR | E | 419 | −32.145 | 56.918 | 38.468 | 1.00 | 17.33 | E | C |
| ATOM | 7716 | OH | TYR | E | 419 | −33.294 | 57.107 | 37.737 | 1.00 | 17.00 | E | O |
| ATOM | 7717 | C | TYR | E | 419 | −27.213 | 54.217 | 41.750 | 1.00 | 16.00 | E | C |
| ATOM | 7718 | O | TYR | E | 419 | −26.217 | 54.204 | 41.024 | 1.00 | 18.58 | E | O |
| ATOM | 7719 | N | GLN | E | 420 | −27.147 | 53.917 | 43.040 | 1.00 | 16.78 | E | N |
| ATOM | 7720 | CA | GLN | E | 420 | −25.870 | 53.540 | 43.634 | 1.00 | 14.63 | E | C |
| ATOM | 7721 | CB | GLN | E | 420 | −25.677 | 54.234 | 44.982 | 1.00 | 17.57 | E | C |
| ATOM | 7722 | CG | GLN | E | 420 | −25.279 | 55.688 | 44.859 | 1.00 | 18.86 | E | C |
| ATOM | 7723 | CD | GLN | E | 420 | −26.418 | 56.551 | 44.361 | 1.00 | 24.20 | E | C |
| ATOM | 7724 | OE1 | GLN | E | 420 | −26.326 | 57.173 | 43.301 | 1.00 | 27.30 | E | O |
| ATOM | 7725 | NE2 | GLN | E | 420 | −27.503 | 56.592 | 45.124 | 1.00 | 23.91 | E | N |
| ATOM | 7726 | C | GLN | E | 420 | −25.772 | 52.029 | 43.809 | 1.00 | 13.35 | E | C |
| ATOM | 7727 | O | GLN | E | 420 | −26.743 | 51.371 | 44.199 | 1.00 | 11.00 | E | O |
| ATOM | 7728 | N | HIS | E | 421 | −24.595 | 51.490 | 43.500 | 1.00 | 9.88 | E | N |
| ATOM | 7729 | CA | HIS | E | 421 | −24.325 | 50.061 | 43.615 | 1.00 | 10.52 | E | C |
| ATOM | 7730 | CB | HIS | E | 421 | −24.015 | 49.465 | 42.234 | 1.00 | 9.74 | E | C |
| ATOM | 7731 | CG | HIS | E | 421 | −25.161 | 49.539 | 41.272 | 1.00 | 11.95 | E | C |
| ATOM | 7732 | CD2 | HIS | E | 421 | −25.722 | 50.592 | 40.628 | 1.00 | 9.43 | E | C |
| ATOM | 7733 | ND1 | HIS | E | 421 | −25.873 | 48.425 | 40.878 | 1.00 | 9.93 | E | N |
| ATOM | 7734 | CE1 | HIS | E | 421 | −26.825 | 48.790 | 40.036 | 1.00 | 7.26 | E | C |
| ATOM | 7735 | NE2 | HIS | E | 421 | −26.753 | 50.098 | 39.866 | 1.00 | 9.81 | E | N |
| ATOM | 7736 | C | HIS | E | 421 | −23.110 | 49.893 | 44.527 | 1.00 | 11.78 | E | C |
| ATOM | 7737 | O | HIS | E | 421 | −22.437 | 50.874 | 44.843 | 1.00 | 11.47 | E | O |
| ATOM | 7738 | N | ALA | E | 422 | −22.816 | 48.656 | 44.927 | 1.00 | 10.93 | E | N |
| ATOM | 7739 | CA | ALA | E | 422 | −21.682 | 48.395 | 45.808 | 1.00 | 10.16 | E | C |
| ATOM | 7740 | CB | ALA | E | 422 | −22.128 | 48.499 | 47.260 | 1.00 | 8.88 | E | C |
| ATOM | 7741 | C | ALA | E | 422 | −21.062 | 47.030 | 45.556 | 1.00 | 10.02 | E | C |
| ATOM | 7742 | O | ALA | E | 422 | −21.750 | 46.103 | 45.144 | 1.00 | 12.33 | E | O |
| ATOM | 7743 | N | GLU | E | 423 | −19.758 | 46.913 | 45.808 | 1.00 | 9.64 | E | N |
| ATOM | 7744 | CA | GLU | E | 423 | −19.030 | 45.657 | 45.617 | 1.00 | 12.86 | E | C |
| ATOM | 7745 | CB | GLU | E | 423 | −17.879 | 45.860 | 44.636 | 1.00 | 11.20 | E | C |
| ATOM | 7746 | CG | GLU | E | 423 | −18.269 | 46.366 | 43.265 | 1.00 | 13.38 | E | C |
| ATOM | 7747 | CD | GLU | E | 423 | −17.097 | 46.325 | 42.296 | 1.00 | 14.67 | E | C |
| ATOM | 7748 | OE1 | GLU | E | 423 | −16.908 | 45.283 | 41.634 | 1.00 | 15.81 | E | O |
| ATOM | 7749 | OE2 | GLU | E | 423 | −16.360 | 47.328 | 42.203 | 1.00 | 12.91 | E | O |
| ATOM | 7750 | C | GLU | E | 423 | −18.461 | 45.147 | 46.950 | 1.00 | 11.84 | E | C |
| ATOM | 7751 | O | GLU | E | 423 | −17.245 | 45.056 | 47.119 | 1.00 | 12.39 | E | O |
| ATOM | 7752 | N | PRO | E | 424 | −19.339 | 44.780 | 47.899 | 1.00 | 14.73 | E | N |
| ATOM | 7753 | CD | PRO | E | 424 | −20.807 | 44.787 | 47.757 | 1.00 | 14.26 | E | C |
| ATOM | 7754 | CA | PRO | E | 424 | −18.932 | 44.284 | 49.219 | 1.00 | 14.10 | E | C |
| ATOM | 7755 | CB | PRO | E | 424 | −20.260 | 44.038 | 49.931 | 1.00 | 13.01 | E | C |
| ATOM | 7756 | CG | PRO | E | 424 | −21.248 | 43.856 | 48.823 | 1.00 | 11.35 | E | C |
| ATOM | 7757 | C | PRO | E | 424 | −18.044 | 43.045 | 49.201 | 1.00 | 14.30 | E | C |
| ATOM | 7758 | O | PRO | E | 424 | −18.314 | 42.077 | 48.495 | 1.00 | 16.31 | E | O |
| ATOM | 7759 | N | ARG | E | 425 | −16.990 | 43.091 | 50.009 | 1.00 | 15.00 | E | N |
| ATOM | 7760 | CA | ARG | E | 425 | −16.014 | 42.011 | 50.130 | 1.00 | 13.23 | E | C |
| ATOM | 7761 | CB | ARG | E | 425 | −14.617 | 42.624 | 50.304 | 1.00 | 8.41 | E | C |
| ATOM | 7762 | CG | ARG | E | 425 | −13.698 | 42.464 | 49.113 | 1.00 | 10.58 | E | C |
| ATOM | 7763 | CD | ARG | E | 425 | −13.127 | 43.781 | 48.619 | 1.00 | 9.34 | E | C |
| ATOM | 7764 | NE | ARG | E | 425 | −14.124 | 44.577 | 47.914 | 1.00 | 13.65 | E | N |
| ATOM | 7765 | CZ | ARG | E | 425 | −13.858 | 45.421 | 46.919 | 1.00 | 12.26 | E | C |
| ATOM | 7766 | NH1 | ARG | E | 425 | −12.614 | 45.597 | 46.491 | 1.00 | 8.46 | E | N |
| ATOM | 7767 | NH2 | ARG | E | 425 | −14.843 | 46.118 | 46.369 | 1.00 | 11.69 | E | N |
| ATOM | 7768 | C | ARG | E | 425 | −16.338 | 41.099 | 51.327 | 1.00 | 14.12 | E | C |
| ATOM | 7769 | O | ARG | E | 425 | −16.566 | 41.585 | 52.435 | 1.00 | 13.78 | E | O |
| ATOM | 7770 | N | LEU | E | 426 | −16.362 | 39.786 | 51.094 | 1.00 | 16.60 | E | N |
| ATOM | 7771 | CA | LEU | E | 426 | −16.637 | 38.791 | 52.137 | 1.00 | 15.24 | E | C |
| ATOM | 7772 | CB | LEU | E | 426 | −17.635 | 37.742 | 51.637 | 1.00 | 13.37 | E | C |
| ATOM | 7773 | CG | LEU | E | 426 | −19.096 | 38.176 | 51.459 | 1.00 | 13.48 | E | C |
| ATOM | 7774 | CD1 | LEU | E | 426 | −19.816 | 37.197 | 50.533 | 1.00 | 10.94 | E | C |
| ATOM | 7775 | CD2 | LEU | E | 426 | −19.786 | 38.231 | 52.820 | 1.00 | 10.21 | E | C |
| ATOM | 7776 | C | LEU | E | 426 | −15.315 | 38.115 | 52.470 | 1.00 | 15.44 | E | C |
| ATOM | 7777 | O | LEU | E | 426 | −14.475 | 37.946 | 51.588 | 1.00 | 16.13 | E | O |
| ATOM | 7778 | N | SER | E | 427 | −15.132 | 37.713 | 53.728 | 1.00 | 16.27 | E | N |
| ATOM | 7779 | CA | SER | E | 427 | −13.875 | 37.095 | 54.152 | 1.00 | 15.76 | E | C |
| ATOM | 7780 | CB | SER | E | 427 | −13.537 | 37.495 | 55.594 | 1.00 | 15.76 | E | C |
| ATOM | 7781 | OG | SER | E | 427 | −13.543 | 38.898 | 55.773 | 1.00 | 17.47 | E | O |
| ATOM | 7782 | C | SER | E | 427 | −13.782 | 35.587 | 54.071 | 1.00 | 14.58 | E | C |
| ATOM | 7783 | O | SER | E | 427 | −14.727 | 34.878 | 54.386 | 1.00 | 18.99 | E | O |
| ATOM | 7784 | N | ILE | E | 428 | −12.612 | 35.121 | 53.651 | 1.00 | 14.63 | E | N |
| ATOM | 7785 | CA | ILE | E | 428 | −12.269 | 33.706 | 53.568 | 1.00 | 15.90 | E | C |
| ATOM | 7786 | CB | ILE | E | 428 | −12.302 | 33.178 | 52.116 | 1.00 | 15.87 | E | C |
| ATOM | 7787 | CG2 | ILE | E | 428 | −11.404 | 31.949 | 51.973 | 1.00 | 12.13 | E | C |
| ATOM | 7788 | CG1 | ILE | E | 428 | −13.745 | 32.837 | 51.724 | 1.00 | 11.69 | E | C |
| ATOM | 7789 | CD1 | ILE | E | 428 | −14.273 | 31.528 | 52.300 | 1.00 | 5.89 | E | C |
| ATOM | 7790 | C | ILE | E | 428 | −10.838 | 33.798 | 54.075 | 1.00 | 18.37 | E | C |
| ATOM | 7791 | O | ILE | E | 428 | −9.969 | 34.318 | 53.386 | 1.00 | 17.95 | E | O |
| ATOM | 7792 | N | TYR | E | 429 | −10.611 | 33.323 | 55.296 | 1.00 | 21.13 | E | N |
| ATOM | 7793 | CA | TYR | E | 429 | −9.300 | 33.428 | 55.936 | 1.00 | 23.62 | E | C |
| ATOM | 7794 | CB | TYR | E | 429 | −9.472 | 33.410 | 57.461 | 1.00 | 21.77 | E | C |
| ATOM | 7795 | CG | TYR | E | 429 | −10.469 | 34.429 | 57.995 | 1.00 | 19.81 | E | C |
| ATOM | 7796 | CD1 | TYR | E | 429 | −11.830 | 34.114 | 58.125 | 1.00 | 19.51 | E | C |
| ATOM | 7797 | CE1 | TYR | E | 429 | −12.745 | 35.044 | 58.629 | 1.00 | 14.20 | E | C |
| ATOM | 7798 | CD2 | TYR | E | 429 | −10.051 | 35.698 | 58.384 | 1.00 | 16.30 | E | C |
| ATOM | 7799 | CE2 | TYR | E | 429 | −10.949 | 36.628 | 58.886 | 1.00 | 14.82 | E | C |
| ATOM | 7800 | CZ | TYR | E | 429 | −12.294 | 36.298 | 59.006 | 1.00 | 18.39 | E | C |
| ATOM | 7801 | OH | TYR | E | 429 | −13.176 | 37.238 | 59.496 | 1.00 | 21.74 | E | O |
| ATOM | 7802 | C | TYR | E | 429 | −8.224 | 32.423 | 55.553 | 1.00 | 24.52 | E | C |
| ATOM | 7803 | O | TYR | E | 429 | −7.039 | 32.750 | 55.569 | 1.00 | 25.64 | E | O |
| ATOM | 7804 | N | GLY | E | 430 | −8.620 | 31.206 | 55.210 | 1.00 | 23.67 | E | N |
| ATOM | 7805 | CA | GLY | E | 430 | −7.624 | 30.210 | 54.872 | 1.00 | 22.83 | E | C |
| ATOM | 7806 | C | GLY | E | 430 | −7.196 | 29.520 | 56.153 | 1.00 | 22.99 | E | C |
| ATOM | 7807 | O | GLY | E | 430 | −6.156 | 28.867 | 56.212 | 1.00 | 24.10 | E | O |
| ATOM | 7808 | N | ARG | E | 431 | −8.017 | 29.672 | 57.186 | 1.00 | 21.77 | E | N |
| ATOM | 7809 | CA | ARG | E | 431 | −7.762 | 29.072 | 58.485 | 1.00 | 23.58 | E | C |
| ATOM | 7810 | CB | ARG | E | 431 | −8.501 | 29.865 | 59.564 | 1.00 | 26.85 | E | C |
| ATOM | 7811 | CG | ARG | E | 431 | −8.451 | 29.246 | 60.955 | 1.00 | 33.58 | E | C |
| ATOM | 7812 | CD | ARG | E | 431 | −9.612 | 29.726 | 61.818 | 1.00 | 38.84 | E | C |
| ATOM | 7813 | NE | ARG | E | 431 | −10.919 | 29.358 | 61.261 | 1.00 | 40.41 | E | N |
| ATOM | 7814 | CZ | ARG | E | 431 | −11.849 | 30.239 | 60.889 | 1.00 | 42.22 | E | C |
| ATOM | 7815 | NH1 | ARG | E | 431 | −11.617 | 31.545 | 61.012 | 1.00 | 42.45 | E | N |
| ATOM | 7816 | NH2 | ARG | E | 431 | −13.016 | 29.819 | 60.408 | 1.00 | 40.55 | E | N |
| ATOM | 7817 | C | ARG | E | 431 | −8.236 | 27.621 | 58.485 | 1.00 | 24.74 | E | C |
| ATOM | 7818 | O | ARG | E | 431 | −7.623 | 26.754 | 59.103 | 1.00 | 21.95 | E | O |
| ATOM | 7819 | N | SER | E | 432 | −9.331 | 27.367 | 57.776 | 1.00 | 28.57 | E | N |
| ATOM | 7820 | CA | SER | E | 432 | −9.908 | 26.030 | 57.684 | 1.00 | 30.13 | E | C |
| ATOM | 7821 | CB | SER | E | 432 | −11.072 | 25.896 | 58.674 | 1.00 | 31.44 | E | C |
| ATOM | 7822 | OG | SER | E | 432 | −11.860 | 24.752 | 58.374 | 1.00 | 35.64 | E | O |
| ATOM | 7823 | C | SER | E | 432 | −10.401 | 25.749 | 56.259 | 1.00 | 32.70 | E | C |
| ATOM | 7824 | O | SER | E | 432 | −10.804 | 26.665 | 55.540 | 1.00 | 34.76 | E | O |
| ATOM | 7825 | N | PRO | E | 433 | −10.396 | 24.471 | 55.841 | 1.00 | 32.31 | E | N |
| ATOM | 7826 | CD | PRO | E | 433 | −9.969 | 23.294 | 56.619 | 1.00 | 32.40 | E | C |
| ATOM | 7827 | CA | PRO | E | 433 | −10.846 | 24.109 | 54.491 | 1.00 | 32.18 | E | C |
| ATOM | 7828 | CB | PRO | E | 433 | −10.200 | 22.749 | 54.252 | 1.00 | 32.34 | E | C |
| ATOM | 7829 | CG | PRO | E | 433 | −10.038 | 22.161 | 55.621 | 1.00 | 32.86 | E | C |
| ATOM | 7830 | C | PRO | E | 433 | −12.361 | 24.075 | 54.281 | 1.00 | 31.20 | E | C |
| ATOM | 7831 | O | PRO | E | 433 | −12.837 | 24.015 | 53.142 | 1.00 | 28.49 | E | O |
| ATOM | 7832 | N | ASP | E | 434 | −13.123 | 24.120 | 55.370 | 1.00 | 28.81 | E | N |
| ATOM | 7833 | CA | ASP | E | 434 | −14.577 | 24.095 | 55.247 | 1.00 | 26.70 | E | C |
| ATOM | 7834 | CB | ASP | E | 434 | −15.189 | 23.276 | 56.394 | 1.00 | 31.54 | E | C |
| ATOM | 7835 | CG | ASP | E | 434 | −15.154 | 24.005 | 57.734 | 1.00 | 39.22 | E | C |
| ATOM | 7836 | OD1 | ASP | E | 434 | −14.265 | 24.858 | 57.945 | 1.00 | 42.93 | E | O |
| ATOM | 7837 | OD2 | ASP | E | 434 | −16.025 | 23.718 | 58.584 | 1.00 | 41.01 | E | O |
| ATOM | 7838 | C | ASP | E | 434 | −15.203 | 25.493 | 55.192 | 1.00 | 24.25 | E | C |
| ATOM | 7839 | O | ASP | E | 434 | −16.430 | 25.629 | 55.209 | 1.00 | 22.12 | E | O |
| ATOM | 7840 | N | GLU | E | 435 | −14.364 | 26.524 | 55.098 | 1.00 | 19.95 | E | N |
| ATOM | 7841 | CA | GLU | E | 435 | −14.847 | 27.902 | 55.055 | 1.00 | 20.80 | E | C |
| ATOM | 7842 | CB | GLU | E | 435 | −13.664 | 28.874 | 55.104 | 1.00 | 20.15 | E | C |
| ATOM | 7843 | CG | GLU | E | 435 | −13.082 | 29.035 | 56.499 | 1.00 | 20.40 | E | C |
| ATOM | 7844 | CD | GLU | E | 435 | −11.950 | 30.030 | 56.552 | 1.00 | 23.38 | E | C |
| ATOM | 7845 | OE1 | GLU | E | 435 | −10.807 | 29.609 | 56.841 | 1.00 | 23.96 | E | O |
| ATOM | 7846 | OE2 | GLU | E | 435 | −12.203 | 31.233 | 56.310 | 1.00 | 25.32 | E | O |
| ATOM | 7847 | C | GLU | E | 435 | −15.715 | 28.205 | 53.838 | 1.00 | 20.84 | E | C |
| ATOM | 7848 | O | GLU | E | 435 | −16.720 | 28.917 | 53.936 | 1.00 | 22.41 | E | O |
| ATOM | 7849 | N | TRP | E | 436 | −15.327 | 27.661 | 52.690 | 1.00 | 20.74 | E | N |
| ATOM | 7850 | CA | TRP | E | 436 | −16.069 | 27.879 | 51.453 | 1.00 | 19.64 | E | C |
| ATOM | 7851 | CB | TRP | E | 436 | −15.276 | 27.332 | 50.263 | 1.00 | 15.88 | E | C |
| ATOM | 7852 | CG | TRP | E | 436 | −14.153 | 28.234 | 49.807 | 1.00 | 13.40 | E | C |
| ATOM | 7853 | CD2 | TRP | E | 436 | −14.274 | 29.414 | 49.000 | 1.00 | 12.78 | E | C |
| ATOM | 7854 | CE2 | TRP | E | 436 | −12.970 | 29.917 | 48.792 | 1.00 | 12.28 | E | C |
| ATOM | 7855 | CE3 | TRP | E | 436 | −15.360 | 30.091 | 48.429 | 1.00 | 14.11 | E | C |
| ATOM | 7856 | CD1 | TRP | E | 436 | −12.819 | 28.076 | 50.053 | 1.00 | 14.83 | E | C |
| ATOM | 7857 | NE1 | TRP | E | 436 | −12.098 | 29.087 | 49.443 | 1.00 | 13.28 | E | N |
| ATOM | 7858 | CZ2 | TRP | E | 436 | −12.724 | 31.069 | 48.040 | 1.00 | 11.75 | E | C |
| ATOM | 7859 | CZ3 | TRP | E | 436 | −15.112 | 31.239 | 47.679 | 1.00 | 12.57 | E | C |
| ATOM | 7860 | CH2 | TRP | E | 436 | −13.806 | 31.712 | 47.492 | 1.00 | 10.59 | E | C |
| ATOM | 7861 | C | TRP | E | 436 | −17.437 | 27.209 | 51.526 | 1.00 | 20.43 | E | C |
| ATOM | 7862 | O | TRP | E | 436 | −18.444 | 27.763 | 51.079 | 1.00 | 20.28 | E | O |
| ATOM | 7863 | N | SER | E | 437 | −17.471 | 26.013 | 52.099 | 1.00 | 22.18 | E | N |
| ATOM | 7864 | CA | SER | E | 437 | −18.722 | 25.282 | 52.237 | 1.00 | 21.07 | E | C |
| ATOM | 7865 | CB | SER | E | 437 | −18.467 | 23.888 | 52.807 | 1.00 | 23.07 | E | C |
| ATOM | 7866 | OG | SER | E | 437 | −19.657 | 23.371 | 53.378 | 1.00 | 25.56 | E | O |
| ATOM | 7867 | C | SER | E | 437 | −19.684 | 26.019 | 53.152 | 1.00 | 20.11 | E | C |
| ATOM | 7868 | O | SER | E | 437 | −20.895 | 26.021 | 52.921 | 1.00 | 19.90 | E | O |
| ATOM | 7869 | N | LYS | E | 438 | −19.145 | 26.637 | 54.199 | 1.00 | 20.42 | E | N |
| ATOM | 7870 | CA | LYS | E | 438 | −19.975 | 27.379 | 55.144 | 1.00 | 20.22 | E | C |
| ATOM | 7871 | CB | LYS | E | 438 | −19.190 | 27.674 | 56.424 | 1.00 | 22.48 | E | C |
| ATOM | 7872 | CG | LYS | E | 438 | −18.616 | 26.451 | 57.108 | 1.00 | 23.54 | E | C |
| ATOM | 7873 | CD | LYS | E | 438 | −18.941 | 26.470 | 58.589 | 1.00 | 26.46 | E | C |
| ATOM | 7874 | CE | LYS | E | 438 | −17.807 | 25.883 | 59.417 | 1.00 | 31.84 | E | C |
| ATOM | 7875 | NZ | LYS | E | 438 | −18.148 | 25.854 | 60.871 | 1.00 | 32.88 | E | N |
| ATOM | 7876 | C | LYS | E | 438 | −20.459 | 28.688 | 54.535 | 1.00 | 17.22 | E | C |
| ATOM | 7877 | O | LYS | E | 438 | −21.633 | 29.037 | 54.648 | 1.00 | 19.16 | E | O |
| ATOM | 7878 | N | LEU | E | 439 | −19.557 | 29.412 | 53.883 | 1.00 | 15.73 | E | N |
| ATOM | 7879 | CA | LEU | E | 439 | −19.926 | 30.686 | 53.281 | 1.00 | 15.31 | E | C |
| ATOM | 7880 | CB | LEU | E | 439 | −18.676 | 31.427 | 52.800 | 1.00 | 13.83 | E | C |
| ATOM | 7881 | CG | LEU | E | 439 | −18.845 | 32.901 | 52.411 | 1.00 | 14.15 | E | C |
| ATOM | 7882 | CD1 | LEU | E | 439 | −19.619 | 33.670 | 53.479 | 1.00 | 11.65 | E | C |
| ATOM | 7883 | CD2 | LEU | E | 439 | −17.466 | 33.502 | 52.208 | 1.00 | 10.71 | E | C |
| ATOM | 7884 | C | LEU | E | 439 | −20.909 | 30.497 | 52.133 | 1.00 | 16.69 | E | C |
| ATOM | 7885 | O | LEU | E | 439 | −21.887 | 31.229 | 52.027 | 1.00 | 18.67 | E | O |
| ATOM | 7886 | N | SER | E | 440 | −20.664 | 29.517 | 51.270 | 1.00 | 18.56 | E | N |
| ATOM | 7887 | CA | SER | E | 440 | −21.583 | 29.289 | 50.158 | 1.00 | 19.87 | E | C |
| ATOM | 7888 | CB | SER | E | 440 | −21.125 | 28.100 | 49.301 | 1.00 | 17.75 | E | C |
| ATOM | 7889 | OG | SER | E | 440 | −21.019 | 26.912 | 50.058 | 1.00 | 19.30 | E | O |
| ATOM | 7890 | C | SER | E | 440 | −22.980 | 29.035 | 50.712 | 1.00 | 19.89 | E | C |
| ATOM | 7891 | O | SER | E | 440 | −23.958 | 29.617 | 50.246 | 1.00 | 22.56 | E | O |
| ATOM | 7892 | N | SER | E | 441 | −23.069 | 28.182 | 51.727 | 1.00 | 19.78 | E | N |
| ATOM | 7893 | CA | SER | E | 441 | −24.353 | 27.861 | 52.345 | 1.00 | 19.34 | E | C |
| ATOM | 7894 | CB | SER | E | 441 | −24.176 | 26.754 | 53.393 | 1.00 | 22.45 | E | C |
| ATOM | 7895 | OG | SER | E | 441 | −23.428 | 25.660 | 52.877 | 1.00 | 27.49 | E | O |
| ATOM | 7896 | C | SER | E | 441 | −24.998 | 29.083 | 52.997 | 1.00 | 18.15 | E | C |
| ATOM | 7897 | O | SER | E | 441 | −26.216 | 29.252 | 52.956 | 1.00 | 17.41 | E | O |
| ATOM | 7898 | N | TRP | E | 442 | −24.183 | 29.934 | 53.607 | 1.00 | 17.66 | E | N |
| ATOM | 7899 | CA | TRP | E | 442 | −24.697 | 31.132 | 54.263 | 1.00 | 18.63 | E | C |
| ATOM | 7900 | CB | TRP | E | 442 | −23.552 | 31.852 | 54.997 | 1.00 | 16.81 | E | C |
| ATOM | 7901 | CG | TRP | E | 442 | −23.889 | 33.227 | 55.507 | 1.00 | 18.77 | E | C |
| ATOM | 7902 | CD2 | TRP | E | 442 | −23.619 | 34.481 | 54.859 | 1.00 | 20.80 | E | C |
| ATOM | 7903 | CE2 | TRP | E | 442 | −24.104 | 35.506 | 55.708 | 1.00 | 18.76 | E | C |
| ATOM | 7904 | CE3 | TRP | E | 442 | −23.017 | 34.838 | 53.644 | 1.00 | 18.97 | E | C |
| ATOM | 7905 | CD1 | TRP | E | 442 | −24.504 | 33.535 | 56.686 | 1.00 | 18.87 | E | C |
| ATOM | 7906 | NE1 | TRP | E | 442 | −24.638 | 34.902 | 56.815 | 1.00 | 17.90 | E | N |
| ATOM | 7907 | CZ2 | TRP | E | 442 | −24.005 | 36.863 | 55.382 | 1.00 | 18.42 | E | C |
| ATOM | 7908 | CZ3 | TRP | E | 442 | −22.918 | 36.196 | 53.320 | 1.00 | 20.13 | E | C |
| ATOM | 7909 | CH2 | TRP | E | 442 | −23.413 | 37.189 | 54.189 | 1.00 | 16.26 | E | C |
| ATOM | 7910 | C | TRP | E | 442 | −25.326 | 32.053 | 53.219 | 1.00 | 18.30 | E | C |
| ATOM | 7911 | O | TRP | E | 442 | −26.415 | 32.592 | 53.422 | 1.00 | 17.03 | E | O |
| ATOM | 7912 | N | PHE | E | 443 | −24.629 | 32.209 | 52.095 | 1.00 | 19.05 | E | N |
| ATOM | 7913 | CA | PHE | E | 443 | −25.066 | 33.062 | 50.992 | 1.00 | 17.66 | E | C |
| ATOM | 7914 | CB | PHE | E | 443 | −23.916 | 33.199 | 49.989 | 1.00 | 19.38 | E | C |
| ATOM | 7915 | CG | PHE | E | 443 | −24.133 | 34.261 | 48.946 | 1.00 | 21.16 | E | C |
| ATOM | 7916 | CD1 | PHE | E | 443 | −24.920 | 34.009 | 47.828 | 1.00 | 22.32 | E | C |
| ATOM | 7917 | CD2 | PHE | E | 443 | −23.538 | 35.509 | 49.073 | 1.00 | 19.91 | E | C |
| ATOM | 7918 | CE1 | PHE | E | 443 | −25.110 | 34.984 | 46.856 | 1.00 | 21.35 | E | C |
| ATOM | 7919 | CE2 | PHE | E | 443 | −23.722 | 36.489 | 48.110 | 1.00 | 18.60 | E | C |
| ATOM | 7920 | CZ | PHE | E | 443 | −24.508 | 36.227 | 46.999 | 1.00 | 20.96 | E | C |
| ATOM | 7921 | C | PHE | E | 443 | −26.320 | 32.548 | 50.280 | 1.00 | 18.87 | E | C |
| ATOM | 7922 | O | PHE | E | 443 | −27.266 | 33.304 | 50.042 | 1.00 | 16.09 | E | O |
| ATOM | 7923 | N | VAL | E | 444 | −26.322 | 31.261 | 49.936 | 1.00 | 19.77 | E | N |
| ATOM | 7924 | CA | VAL | E | 444 | −27.451 | 30.657 | 49.243 | 1.00 | 20.11 | E | C |
| ATOM | 7925 | CB | VAL | E | 444 | −27.083 | 29.255 | 48.717 | 1.00 | 22.30 | E | C |
| ATOM | 7926 | CG1 | VAL | E | 444 | −28.243 | 28.673 | 47.924 | 1.00 | 20.77 | E | C |
| ATOM | 7927 | CG2 | VAL | E | 444 | −25.834 | 29.333 | 47.854 | 1.00 | 18.32 | E | C |
| ATOM | 7928 | C | VAL | E | 444 | −28.681 | 30.531 | 50.137 | 1.00 | 22.33 | E | C |
| ATOM | 7929 | O | VAL | E | 444 | −29.775 | 30.972 | 49.778 | 1.00 | 22.71 | E | O |
| ATOM | 7930 | N | ARG | E | 445 | −28.498 | 29.927 | 51.305 | 1.00 | 25.19 | E | N |
| ATOM | 7931 | CA | ARG | E | 445 | −29.598 | 29.722 | 52.239 | 1.00 | 26.16 | E | C |
| ATOM | 7932 | CB | ARG | E | 445 | −29.109 | 28.947 | 53.455 | 1.00 | 28.88 | E | C |
| ATOM | 7933 | CG | ARG | E | 445 | −29.287 | 27.454 | 53.333 | 1.00 | 34.88 | E | C |
| ATOM | 7934 | CD | ARG | E | 445 | −28.200 | 26.724 | 54.090 | 1.00 | 40.38 | E | C |
| ATOM | 7935 | NE | ARG | E | 445 | −27.739 | 25.545 | 53.369 | 1.00 | 42.39 | E | N |
| ATOM | 7936 | CZ | ARG | E | 445 | −27.330 | 24.430 | 53.957 | 1.00 | 45.35 | E | C |
| ATOM | 7937 | NH1 | ARG | E | 445 | −27.323 | 24.335 | 55.281 | 1.00 | 45.02 | E | N |
| ATOM | 7938 | NH2 | ARG | E | 445 | −26.934 | 23.409 | 53.217 | 1.00 | 46.76 | E | N |
| ATOM | 7939 | C | ARG | E | 445 | −30.262 | 31.009 | 52.701 | 1.00 | 26.12 | E | C |
| ATOM | 7940 | O | ARG | E | 445 | −31.458 | 31.029 | 52.989 | 1.00 | 25.19 | E | O |
| ATOM | 7941 | N | ASN | E | 446 | −29.490 | 32.085 | 52.783 | 1.00 | 24.67 | E | N |
| ATOM | 7942 | CA | ASN | E | 446 | −30.044 | 33.355 | 53.223 | 1.00 | 22.43 | E | C |
| ATOM | 7943 | CB | ASN | E | 446 | −28.998 | 34.125 | 54.031 | 1.00 | 23.88 | E | C |
| ATOM | 7944 | CG | ASN | E | 446 | −28.896 | 33.634 | 55.472 | 1.00 | 22.42 | E | C |
| ATOM | 7945 | OD1 | ASN | E | 446 | −27.982 | 32.890 | 55.831 | 1.00 | 19.81 | E | O |
| ATOM | 7946 | ND2 | ASN | E | 446 | −29.841 | 34.051 | 56.302 | 1.00 | 23.29 | E | N |
| ATOM | 7947 | C | ASN | E | 446 | −30.531 | 34.182 | 52.042 | 1.00 | 23.81 | E | C |
| ATOM | 7948 | O | ASN | E | 446 | −31.058 | 35.277 | 52.221 | 1.00 | 20.52 | E | O |
| ATOM | 7949 | N | ARG | E | 447 | −30.358 | 33.642 | 50.837 | 1.00 | 24.71 | E | N |
| ATOM | 7950 | CA | ARG | E | 447 | −30.786 | 34.308 | 49.608 | 1.00 | 26.91 | E | C |
| ATOM | 7951 | CB | ARG | E | 447 | −32.315 | 34.352 | 49.519 | 1.00 | 27.16 | E | C |
| ATOM | 7952 | CG | ARG | E | 447 | −33.008 | 33.099 | 50.033 | 1.00 | 35.92 | E | C |
| ATOM | 7953 | CD | ARG | E | 447 | −33.376 | 32.150 | 48.900 | 1.00 | 40.20 | E | C |
| ATOM | 7954 | NE | ARG | E | 447 | −34.212 | 32.810 | 47.898 | 1.00 | 44.07 | E | N |
| ATOM | 7955 | CZ | ARG | E | 447 | −34.365 | 32.377 | 46.649 | 1.00 | 44.66 | E | C |
| ATOM | 7956 | NH1 | ARG | E | 447 | −33.744 | 31.278 | 46.239 | 1.00 | 44.14 | E | N |
| ATOM | 7957 | NH2 | ARG | E | 447 | −35.133 | 33.050 | 45.804 | 1.00 | 46.31 | E | N |
| ATOM | 7958 | C | ARG | E | 447 | −30.243 | 35.720 | 49.505 | 1.00 | 25.73 | E | C |
| ATOM | 7959 | O | ARG | E | 447 | −30.991 | 36.664 | 49.245 | 1.00 | 24.60 | E | O |
| ATOM | 7960 | N | ILE | E | 448 | −28.942 | 35.865 | 49.717 | 1.00 | 26.00 | E | N |
| ATOM | 7961 | CA | ILE | E | 448 | −28.318 | 37.176 | 49.633 | 1.00 | 28.87 | E | C |
| ATOM | 7962 | CB | ILE | E | 448 | −26.995 | 37.219 | 50.427 | 1.00 | 27.46 | E | C |
| ATOM | 7963 | CG2 | ILE | E | 448 | −26.203 | 38.457 | 50.063 | 1.00 | 27.47 | E | C |
| ATOM | 7964 | CG1 | ILE | E | 448 | −27.290 | 37.230 | 51.923 | 1.00 | 25.01 | E | C |
| ATOM | 7965 | CD1 | ILE | E | 448 | −26.468 | 36.249 | 52.684 | 1.00 | 27.34 | E | C |
| ATOM | 7966 | C | ILE | E | 448 | −28.037 | 37.485 | 48.168 | 1.00 | 30.71 | E | C |
| ATOM | 7967 | O | ILE | E | 448 | −27.097 | 36.961 | 47.576 | 1.00 | 35.27 | E | O |
| ATOM | 7968 | N | TYR | E | 449 | −28.873 | 38.322 | 47.576 | 1.00 | 29.04 | E | N |
| ATOM | 7969 | CA | TYR | E | 449 | −28.702 | 38.700 | 46.187 | 1.00 | 26.52 | E | C |
| ATOM | 7970 | CB | TYR | E | 449 | −29.233 | 37.614 | 45.238 | 1.00 | 27.14 | E | C |
| ATOM | 7971 | CG | TYR | E | 449 | −29.478 | 38.142 | 43.840 | 1.00 | 29.26 | E | C |
| ATOM | 7972 | CD1 | TYR | E | 449 | −28.435 | 38.243 | 42.918 | 1.00 | 28.53 | E | C |
| ATOM | 7973 | CE1 | TYR | E | 449 | −28.627 | 38.843 | 41.675 | 1.00 | 28.81 | E | C |
| ATOM | 7974 | CD2 | TYR | E | 449 | −30.726 | 38.647 | 43.473 | 1.00 | 30.91 | E | C |
| ATOM | 7975 | CE2 | TYR | E | 449 | −30.927 | 39.250 | 42.230 | 1.00 | 30.94 | E | C |
| ATOM | 7976 | CZ | TYR | E | 449 | −29.872 | 39.347 | 41.339 | 1.00 | 30.77 | E | C |
| ATOM | 7977 | OH | TYR | E | 449 | −30.057 | 39.970 | 40.125 | 1.00 | 32.69 | E | O |
| ATOM | 7978 | C | TYR | E | 449 | −29.490 | 39.975 | 45.993 | 1.00 | 24.94 | E | C |
| ATOM | 7979 | O | TYR | E | 449 | −30.705 | 39.996 | 46.173 | 1.00 | 26.98 | E | O |
| ATOM | 7980 | N | SER | E | 450 | −28.793 | 41.044 | 45.642 | 1.00 | 21.21 | E | N |
| ATOM | 7981 | CA | SER | E | 450 | −29.443 | 42.320 | 45.419 | 1.00 | 21.39 | E | C |
| ATOM | 7982 | CB | SER | E | 450 | −28.945 | 43.350 | 46.438 | 1.00 | 16.62 | E | C |
| ATOM | 7983 | OG | SER | E | 450 | −29.298 | 44.675 | 46.075 | 1.00 | 17.70 | E | O |
| ATOM | 7984 | C | SER | E | 450 | −29.071 | 42.729 | 44.003 | 1.00 | 21.59 | E | C |
| ATOM | 7985 | O | SER | E | 450 | −27.955 | 42.464 | 43.548 | 1.00 | 21.34 | E | O |
| ATOM | 7986 | N | SER | E | 451 | −30.004 | 43.351 | 43.297 | 1.00 | 21.83 | E | N |
| ATOM | 7987 | CA | SER | E | 451 | −29.724 | 43.767 | 41.936 | 1.00 | 23.93 | E | C |
| ATOM | 7988 | CB | SER | E | 451 | −31.016 | 44.161 | 41.235 | 1.00 | 21.48 | E | C |
| ATOM | 7989 | OG | SER | E | 451 | −31.587 | 45.271 | 41.887 | 1.00 | 27.14 | E | O |
| ATOM | 7990 | C | SER | E | 451 | −28.750 | 44.940 | 41.940 | 1.00 | 23.10 | E | C |
| ATOM | 7991 | O | SER | E | 451 | −28.290 | 45.366 | 40.880 | 1.00 | 26.21 | E | O |
| ATOM | 7992 | N | ASN | E | 452 | −28.437 | 45.451 | 43.134 | 1.00 | 21.20 | E | N |
| ATOM | 7993 | CA | ASN | E | 452 | −27.512 | 46.579 | 43.284 | 1.00 | 17.69 | E | C |
| ATOM | 7994 | CB | ASN | E | 452 | −28.205 | 47.744 | 43.974 | 1.00 | 15.58 | E | C |
| ATOM | 7995 | CG | ASN | E | 452 | −29.092 | 48.519 | 43.039 | 1.00 | 16.32 | E | C |
| ATOM | 7996 | OD1 | ASN | E | 452 | −30.128 | 48.027 | 42.604 | 1.00 | 15.94 | E | O |
| ATOM | 7997 | ND2 | ASN | E | 452 | −28.690 | 49.743 | 42.722 | 1.00 | 14.59 | E | N |
| ATOM | 7998 | C | ASN | E | 452 | −26.236 | 46.247 | 44.051 | 1.00 | 15.75 | E | C |
| ATOM | 7999 | O | ASN | E | 452 | −25.539 | 47.150 | 44.514 | 1.00 | 11.22 | E | O |
| ATOM | 8000 | N | MET | E | 453 | −25.933 | 44.958 | 44.180 | 1.00 | 13.34 | E | N |
| ATOM | 8001 | CA | MET | E | 453 | −24.734 | 44.518 | 44.880 | 1.00 | 12.94 | E | C |
| ATOM | 8002 | CB | MET | E | 453 | −25.083 | 44.035 | 46.292 | 1.00 | 12.53 | E | C |
| ATOM | 8003 | CG | MET | E | 453 | −25.215 | 45.128 | 47.331 | 1.00 | 18.90 | E | C |
| ATOM | 8004 | SD | MET | E | 453 | −25.535 | 44.458 | 48.979 | 1.00 | 24.46 | E | S |
| ATOM | 8005 | CE | MET | E | 453 | −25.051 | 45.858 | 50.013 | 1.00 | 23.71 | E | C |
| ATOM | 8006 | C | MET | E | 453 | −24.084 | 43.368 | 44.130 | 1.00 | 13.28 | E | C |
| ATOM | 8007 | O | MET | E | 453 | −24.781 | 42.495 | 43.635 | 1.00 | 14.12 | E | O |
| ATOM | 8008 | N | THR | E | 454 | −22.757 | 43.391 | 44.023 | 1.00 | 13.27 | E | N |
| ATOM | 8009 | CA | THR | E | 454 | −22.001 | 42.307 | 43.397 | 1.00 | 13.43 | E | C |
| ATOM | 8010 | CB | THR | E | 454 | −21.297 | 42.716 | 42.059 | 1.00 | 15.15 | E | C |
| ATOM | 8011 | OG1 | THR | E | 454 | −20.759 | 44.040 | 42.149 | 1.00 | 16.55 | E | O |
| ATOM | 8012 | CG2 | THR | E | 454 | −22.300 | 42.665 | 40.915 | 1.00 | 9.69 | E | C |
| ATOM | 8013 | C | THR | E | 454 | −20.980 | 41.961 | 44.467 | 1.00 | 13.97 | E | C |
| ATOM | 8014 | O | THR | E | 454 | −20.647 | 42.809 | 45.292 | 1.00 | 14.77 | E | O |
| ATOM | 8015 | N | TRP | E | 455 | −20.473 | 40.735 | 44.452 | 1.00 | 14.73 | E | N |
| ATOM | 8016 | CA | TRP | E | 455 | −19.569 | 40.284 | 45.497 | 1.00 | 12.68 | E | C |
| ATOM | 8017 | CB | TRP | E | 455 | −20.260 | 39.152 | 46.263 | 1.00 | 14.65 | E | C |
| ATOM | 8018 | CG | TRP | E | 455 | −21.598 | 39.554 | 46.803 | 1.00 | 13.97 | E | C |
| ATOM | 8019 | CD2 | TRP | E | 455 | −21.871 | 40.055 | 48.114 | 1.00 | 13.92 | E | C |
| ATOM | 8020 | CE2 | TRP | E | 455 | −23.250 | 40.358 | 48.170 | 1.00 | 12.98 | E | C |
| ATOM | 8021 | CE3 | TRP | E | 455 | −21.082 | 40.279 | 49.247 | 1.00 | 12.87 | E | C |
| ATOM | 8022 | CD1 | TRP | E | 455 | −22.790 | 39.566 | 46.133 | 1.00 | 12.20 | E | C |
| ATOM | 8023 | NE1 | TRP | E | 455 | −23.791 | 40.049 | 46.947 | 1.00 | 11.63 | E | N |
| ATOM | 8024 | CZ2 | TRP | E | 455 | −23.856 | 40.874 | 49.315 | 1.00 | 13.80 | E | C |
| ATOM | 8025 | CZ3 | TRP | E | 455 | −21.686 | 40.792 | 50.386 | 1.00 | 17.79 | E | C |
| ATOM | 8026 | CH2 | TRP | E | 455 | −23.062 | 41.084 | 50.410 | 1.00 | 15.37 | E | C |
| ATOM | 8027 | C | TRP | E | 455 | −18.163 | 39.841 | 45.138 | 1.00 | 13.56 | E | C |
| ATOM | 8028 | O | TRP | E | 455 | −17.910 | 39.361 | 44.038 | 1.00 | 14.68 | E | O |
| ATOM | 8029 | N | MET | E | 456 | −17.265 | 39.989 | 46.112 | 1.00 | 13.89 | E | N |
| ATOM | 8030 | CA | MET | E | 456 | −15.862 | 39.602 | 45.993 | 1.00 | 13.27 | E | C |
| ATOM | 8031 | CB | MET | E | 456 | −14.980 | 40.826 | 45.783 | 1.00 | 11.69 | E | C |
| ATOM | 8032 | CG | MET | E | 456 | −15.326 | 41.645 | 44.563 | 1.00 | 13.32 | E | C |
| ATOM | 8033 | SD | MET | E | 456 | −14.236 | 43.078 | 44.397 | 1.00 | 19.11 | E | S |
| ATOM | 8034 | CE | MET | E | 456 | −12.647 | 42.375 | 44.761 | 1.00 | 12.48 | E | C |
| ATOM | 8035 | C | MET | E | 456 | −15.429 | 38.919 | 47.284 | 1.00 | 14.08 | E | C |
| ATOM | 8036 | O | MET | E | 456 | −16.132 | 38.978 | 48.289 | 1.00 | 12.67 | E | O |
| ATOM | 8037 | N | ILE | E | 457 | −14.272 | 38.269 | 47.251 | 1.00 | 14.96 | E | N |
| ATOM | 8038 | CA | ILE | E | 457 | −13.740 | 37.603 | 48.431 | 1.00 | 14.22 | E | C |
| ATOM | 8039 | CB | ILE | E | 457 | −13.546 | 36.085 | 48.197 | 1.00 | 15.76 | E | C |
| ATOM | 8040 | CG2 | ILE | E | 457 | −12.406 | 35.547 | 49.060 | 1.00 | 12.69 | E | C |
| ATOM | 8041 | CG1 | ILE | E | 457 | −14.815 | 35.342 | 48.605 | 1.00 | 17.51 | E | C |
| ATOM | 8042 | CD1 | ILE | E | 457 | −15.483 | 34.664 | 47.473 | 1.00 | 20.18 | E | C |
| ATOM | 8043 | C | ILE | E | 457 | −12.407 | 38.229 | 48.817 | 1.00 | 13.87 | E | C |
| ATOM | 8044 | O | ILE | E | 457 | −11.581 | 38.535 | 47.961 | 1.00 | 16.54 | E | O |
| ATOM | 8045 | N | GLN | E | 458 | −12.206 | 38.432 | 50.111 | 1.00 | 13.71 | E | N |
| ATOM | 8046 | CA | GLN | E | 458 | −10.971 | 39.023 | 50.597 | 1.00 | 13.41 | E | C |
| ATOM | 8047 | CB | GLN | E | 458 | −11.264 | 40.323 | 51.349 | 1.00 | 13.80 | E | C |
| ATOM | 8048 | CG | GLN | E | 458 | −12.221 | 40.143 | 52.514 | 1.00 | 17.65 | E | C |
| ATOM | 8049 | CD | GLN | E | 458 | −12.477 | 41.424 | 53.298 | 1.00 | 22.20 | E | C |
| ATOM | 8050 | OE1 | GLN | E | 458 | −12.308 | 42.536 | 52.788 | 1.00 | 21.56 | E | O |
| ATOM | 8051 | NE2 | GLN | E | 458 | −12.895 | 41.269 | 54.549 | 1.00 | 22.18 | E | N |
| ATOM | 8052 | C | GLN | E | 458 | −10.305 | 38.040 | 51.538 | 1.00 | 13.67 | E | C |
| ATOM | 8053 | O | GLN | E | 458 | −10.976 | 37.359 | 52.316 | 1.00 | 13.80 | E | O |
| ATOM | 8054 | N | VAL | E | 459 | −8.988 | 37.942 | 51.450 | 1.00 | 11.28 | E | N |
| ATOM | 8055 | CA | VAL | E | 459 | −8.273 | 37.066 | 52.341 | 1.00 | 14.75 | E | C |
| ATOM | 8056 | CB | VAL | E | 459 | −7.632 | 35.847 | 51.585 | 1.00 | 14.19 | E | C |
| ATOM | 8057 | CG1 | VAL | E | 459 | −8.044 | 35.866 | 50.139 | 1.00 | 15.40 | E | C |
| ATOM | 8058 | CG2 | VAL | E | 459 | −6.117 | 35.825 | 51.742 | 1.00 | 14.50 | E | C |
| ATOM | 8059 | C | VAL | E | 459 | −7.243 | 37.937 | 53.049 | 1.00 | 16.71 | E | C |
| ATOM | 8060 | O | VAL | E | 459 | −6.277 | 38.402 | 52.447 | 1.00 | 18.77 | E | O |
| ATOM | 8061 | N | PRO | E | 460 | −7.487 | 38.227 | 54.341 | 1.00 | 20.70 | E | N |
| ATOM | 8062 | CD | PRO | E | 460 | −8.666 | 37.820 | 55.128 | 1.00 | 16.73 | E | C |
| ATOM | 8063 | CA | PRO | E | 460 | −6.566 | 39.055 | 55.126 | 1.00 | 20.32 | E | C |
| ATOM | 8064 | CB | PRO | E | 460 | −7.257 | 39.170 | 56.482 | 1.00 | 18.77 | E | C |
| ATOM | 8065 | CG | PRO | E | 460 | −8.711 | 38.848 | 56.202 | 1.00 | 18.07 | E | C |
| ATOM | 8066 | C | PRO | E | 460 | −5.201 | 38.392 | 55.221 | 1.00 | 19.24 | E | C |
| ATOM | 8067 | O | PRO | E | 460 | −5.107 | 37.176 | 55.321 | 1.00 | 21.20 | E | O |
| ATOM | 8068 | N | ARG | E | 461 | −4.144 | 39.192 | 55.168 | 1.00 | 19.92 | E | N |
| ATOM | 8069 | CA | ARG | E | 461 | −2.792 | 38.658 | 55.242 | 1.00 | 21.95 | E | C |
| ATOM | 8070 | CB | ARG | E | 461 | −1.820 | 39.589 | 54.504 | 1.00 | 18.94 | E | C |
| ATOM | 8071 | CG | ARG | E | 461 | −2.256 | 39.964 | 53.100 | 1.00 | 16.07 | E | C |
| ATOM | 8072 | CD | ARG | E | 461 | −1.138 | 40.662 | 52.321 | 1.00 | 15.62 | E | C |
| ATOM | 8073 | NE | ARG | E | 461 | −0.862 | 41.998 | 52.840 | 1.00 | 12.29 | E | N |
| ATOM | 8074 | CZ | ARG | E | 461 | −1.596 | 43.073 | 52.574 | 1.00 | 13.49 | E | C |
| ATOM | 8075 | NH1 | ARG | E | 461 | −2.658 | 42.985 | 51.790 | 1.00 | 15.37 | E | N |
| ATOM | 8076 | NH2 | ARG | E | 461 | −1.280 | 44.243 | 53.114 | 1.00 | 14.80 | E | N |
| ATOM | 8077 | C | ARG | E | 461 | −2.378 | 38.518 | 56.709 | 1.00 | 24.94 | E | C |
| ATOM | 8078 | O | ARG | E | 461 | −1.525 | 39.268 | 57.211 | 1.00 | 25.13 | E | O |
| ATOM | 8079 | N | ILE | E | 462 | −2.990 | 37.556 | 57.396 | 1.00 | 24.89 | E | N |
| ATOM | 8080 | CA | ILE | E | 462 | −2.690 | 37.329 | 58.804 | 1.00 | 22.11 | E | C |
| ATOM | 8081 | CB | ILE | E | 462 | −3.909 | 37.677 | 59.689 | 1.00 | 19.07 | E | C |
| ATOM | 8082 | CG2 | ILE | E | 462 | −4.284 | 39.156 | 59.510 | 1.00 | 13.28 | E | C |
| ATOM | 8083 | CG1 | ILE | E | 462 | −5.086 | 36.772 | 59.329 | 1.00 | 16.21 | E | C |
| ATOM | 8084 | CD1 | ILE | E | 462 | −6.338 | 37.047 | 60.142 | 1.00 | 15.61 | E | C |
| ATOM | 8085 | C | ILE | E | 462 | −2.254 | 35.891 | 59.078 | 1.00 | 23.77 | E | C |
| ATOM | 8086 | O | ILE | E | 462 | −2.682 | 35.274 | 60.056 | 1.00 | 25.25 | E | O |
| ATOM | 8087 | N | TYR | E | 463 | −1.397 | 35.358 | 58.212 | 1.00 | 24.16 | E | N |
| ATOM | 8088 | CA | TYR | E | 463 | −0.907 | 33.997 | 58.381 | 1.00 | 24.14 | E | C |
| ATOM | 8089 | CB | TYR | E | 463 | 0.068 | 33.634 | 57.260 | 1.00 | 23.82 | E | C |
| ATOM | 8090 | CG | TYR | E | 463 | 1.033 | 32.527 | 57.625 | 1.00 | 23.27 | E | C |
| ATOM | 8091 | CD1 | TYR | E | 463 | 0.693 | 31.187 | 57.437 | 1.00 | 22.24 | E | C |
| ATOM | 8092 | CE1 | TYR | E | 463 | 1.575 | 30.159 | 57.793 | 1.00 | 22.73 | E | C |
| ATOM | 8093 | CD2 | TYR | E | 463 | 2.283 | 32.819 | 58.176 | 1.00 | 22.92 | E | C |
| ATOM | 8094 | CE2 | TYR | E | 463 | 3.174 | 31.802 | 58.534 | 1.00 | 21.40 | E | C |
| ATOM | 8095 | CZ | TYR | E | 463 | 2.814 | 30.478 | 58.343 | 1.00 | 23.26 | E | C |
| ATOM | 8096 | OH | TYR | E | 463 | 3.691 | 29.482 | 58.708 | 1.00 | 23.81 | E | O |
| ATOM | 8097 | C | TYR | E | 463 | −0.201 | 33.885 | 59.722 | 1.00 | 26.84 | E | C |
| ATOM | 8098 | O | TYR | E | 463 | −0.407 | 32.922 | 60.467 | 1.00 | 27.89 | E | O |
| ATOM | 8099 | N | ASP | E | 464 | 0.631 | 34.878 | 60.028 | 1.00 | 26.50 | E | N |
| ATOM | 8100 | CA | ASP | E | 464 | 1.381 | 34.896 | 61.279 | 1.00 | 26.05 | E | C |
| ATOM | 8101 | CB | ASP | E | 464 | 2.161 | 36.216 | 61.409 | 1.00 | 27.11 | E | C |
| ATOM | 8102 | CG | ASP | E | 464 | 1.283 | 37.449 | 61.219 | 1.00 | 30.05 | E | C |
| ATOM | 8103 | OD1 | ASP | E | 464 | 1.750 | 38.558 | 61.542 | 1.00 | 31.84 | E | O |
| ATOM | 8104 | OD2 | ASP | E | 464 | 0.131 | 37.320 | 60.751 | 1.00 | 32.37 | E | O |
| ATOM | 8105 | C | ASP | E | 464 | 0.482 | 34.689 | 62.501 | 1.00 | 26.05 | E | C |
| ATOM | 8106 | O | ASP | E | 464 | 0.891 | 34.074 | 63.482 | 1.00 | 26.89 | E | O |
| ATOM | 8107 | N | VAL | E | 465 | −0.746 | 35.191 | 62.441 | 1.00 | 27.19 | E | N |
| ATOM | 8108 | CA | VAL | E | 465 | −1.676 | 35.042 | 63.556 | 1.00 | 26.22 | E | C |
| ATOM | 8109 | CB | VAL | E | 465 | −2.888 | 35.968 | 63.381 | 1.00 | 24.76 | E | C |
| ATOM | 8110 | CG1 | VAL | E | 465 | −3.955 | 35.645 | 64.410 | 1.00 | 27.71 | E | C |
| ATOM | 8111 | CG2 | VAL | E | 465 | −2.453 | 37.401 | 63.522 | 1.00 | 25.37 | E | C |
| ATOM | 8112 | C | VAL | E | 465 | −2.163 | 33.596 | 63.683 | 1.00 | 30.84 | E | C |
| ATOM | 8113 | O | VAL | E | 465 | −2.169 | 33.029 | 64.781 | 1.00 | 30.59 | E | O |
| ATOM | 8114 | N | PHE | E | 466 | −2.567 | 33.006 | 62.556 | 1.00 | 32.08 | E | N |
| ATOM | 8115 | CA | PHE | E | 466 | −3.056 | 31.628 | 62.538 | 1.00 | 31.12 | E | C |
| ATOM | 8116 | CB | PHE | E | 466 | −3.656 | 31.288 | 61.168 | 1.00 | 28.28 | E | C |
| ATOM | 8117 | CG | PHE | E | 466 | −4.921 | 32.031 | 60.861 | 1.00 | 28.98 | E | C |
| ATOM | 8118 | CD1 | PHE | E | 466 | −5.869 | 32.262 | 61.853 | 1.00 | 29.84 | E | C |
| ATOM | 8119 | CD2 | PHE | E | 466 | −5.151 | 32.533 | 59.587 | 1.00 | 30.10 | E | C |
| ATOM | 8120 | CE1 | PHE | E | 466 | −7.028 | 32.988 | 61.582 | 1.00 | 31.76 | E | C |
| ATOM | 8121 | CE2 | PHE | E | 466 | −6.307 | 33.261 | 59.304 | 1.00 | 30.16 | E | C |
| ATOM | 8122 | CZ | PHE | E | 466 | −7.246 | 33.490 | 60.305 | 1.00 | 30.82 | E | C |
| ATOM | 8123 | C | PHE | E | 466 | −1.939 | 30.646 | 62.855 | 1.00 | 30.68 | E | C |
| ATOM | 8124 | O | PHE | E | 466 | −2.161 | 29.620 | 63.491 | 1.00 | 32.00 | E | O |
| ATOM | 8125 | N | ARG | E | 467 | −0.735 | 30.969 | 62.408 | 1.00 | 31.02 | E | N |
| ATOM | 8126 | CA | ARG | E | 467 | 0.417 | 30.109 | 62.636 | 1.00 | 33.96 | E | C |
| ATOM | 8127 | CB | ARG | E | 467 | 1.593 | 30.588 | 61.784 | 1.00 | 32.86 | E | C |
| ATOM | 8128 | CG | ARG | E | 467 | 2.878 | 29.839 | 62.036 | 1.00 | 32.39 | E | C |
| ATOM | 8129 | CD | ARG | E | 467 | 2.770 | 28.390 | 61.598 | 1.00 | 35.83 | E | C |
| ATOM | 8130 | NE | ARG | E | 467 | 3.982 | 27.653 | 61.940 | 1.00 | 41.47 | E | N |
| ATOM | 8131 | CZ | ARG | E | 467 | 4.344 | 27.362 | 63.187 | 1.00 | 46.10 | E | C |
| ATOM | 8132 | NH1 | ARG | E | 467 | 3.583 | 27.747 | 64.210 | 1.00 | 47.42 | E | N |
| ATOM | 8133 | NH2 | ARG | E | 467 | 5.482 | 26.716 | 63.416 | 1.00 | 46.33 | E | N |
| ATOM | 8134 | C | ARG | E | 467 | 0.844 | 30.049 | 64.106 | 1.00 | 36.66 | E | C |
| ATOM | 8135 | O | ARG | E | 467 | 1.191 | 28.980 | 64.621 | 1.00 | 38.61 | E | O |
| ATOM | 8136 | N | SER | E | 468 | 0.829 | 31.196 | 64.780 | 1.00 | 36.68 | E | N |
| ATOM | 8137 | CA | SER | E | 468 | 1.234 | 31.255 | 66.181 | 1.00 | 35.81 | E | C |
| ATOM | 8138 | CB | SER | E | 468 | 1.412 | 32.716 | 66.614 | 1.00 | 34.14 | E | C |
| ATOM | 8139 | OG | SER | E | 468 | 0.287 | 33.500 | 66.243 | 1.00 | 35.36 | E | O |
| ATOM | 8140 | C | SER | E | 468 | 0.212 | 30.555 | 67.078 | 1.00 | 36.40 | E | C |
| ATOM | 8141 | O | SER | E | 468 | 0.526 | 30.178 | 68.208 | 1.00 | 37.15 | E | O |
| ATOM | 8142 | N | LYS | E | 469 | −1.006 | 30.390 | 66.568 | 1.00 | 34.25 | E | N |
| ATOM | 8143 | CA | LYS | E | 469 | −2.080 | 29.728 | 67.300 | 1.00 | 30.63 | E | C |
| ATOM | 8144 | CB | LYS | E | 469 | −3.430 | 30.353 | 66.942 | 1.00 | 32.14 | E | C |
| ATOM | 8145 | CG | LYS | E | 469 | −3.875 | 31.490 | 67.847 | 1.00 | 34.84 | E | C |
| ATOM | 8146 | CD | LYS | E | 469 | −5.229 | 32.034 | 67.400 | 1.00 | 38.19 | E | C |
| ATOM | 8147 | CE | LYS | E | 469 | −5.670 | 33.212 | 68.252 | 1.00 | 39.08 | E | C |
| ATOM | 8148 | NZ | LYS | E | 469 | −4.730 | 34.360 | 68.144 | 1.00 | 41.66 | E | N |
| ATOM | 8149 | C | LYS | E | 469 | −2.082 | 28.269 | 66.872 | 1.00 | 32.07 | E | C |
| ATOM | 8150 | O | LYS | E | 469 | −2.958 | 27.490 | 67.251 | 1.00 | 32.66 | E | O |
| ATOM | 8151 | N | ASN | E | 470 | −1.096 | 27.907 | 66.062 | 1.00 | 33.18 | E | N |
| ATOM | 8152 | CA | ASN | E | 470 | −0.976 | 26.546 | 65.564 | 1.00 | 33.63 | E | C |
| ATOM | 8153 | CB | ASN | E | 470 | −0.626 | 25.614 | 66.714 | 1.00 | 36.64 | E | C |
| ATOM | 8154 | CG | ASN | E | 470 | 0.764 | 25.886 | 67.260 | 1.00 | 41.29 | E | C |
| ATOM | 8155 | OD1 | ASN | E | 470 | 1.767 | 25.665 | 66.571 | 1.00 | 40.02 | E | O |
| ATOM | 8156 | ND2 | ASN | E | 470 | 0.835 | 26.384 | 68.499 | 1.00 | 43.99 | E | N |
| ATOM | 8157 | C | ASN | E | 470 | −2.237 | 26.079 | 64.852 | 1.00 | 33.13 | E | C |
| ATOM | 8158 | O | ASN | E | 470 | −2.640 | 24.922 | 64.951 | 1.00 | 31.58 | E | O |
| ATOM | 8159 | N | PHE | E | 471 | −2.854 | 27.004 | 64.127 | 1.00 | 35.04 | E | N |
| ATOM | 8160 | CA | PHE | E | 471 | −4.049 | 26.716 | 63.351 | 1.00 | 34.29 | E | C |
| ATOM | 8161 | CB | PHE | E | 471 | −4.870 | 27.992 | 63.157 | 1.00 | 34.04 | E | C |
| ATOM | 8162 | CG | PHE | E | 471 | −5.840 | 28.265 | 64.261 | 1.00 | 35.03 | E | C |
| ATOM | 8163 | CD1 | PHE | E | 471 | −5.970 | 27.385 | 65.331 | 1.00 | 37.58 | E | C |
| ATOM | 8164 | CD2 | PHE | E | 471 | −6.646 | 29.399 | 64.221 | 1.00 | 38.50 | E | C |
| ATOM | 8165 | CE1 | PHE | E | 471 | −6.894 | 27.629 | 66.351 | 1.00 | 40.66 | E | C |
| ATOM | 8166 | CE2 | PHE | E | 471 | −7.575 | 29.657 | 65.232 | 1.00 | 41.62 | E | C |
| ATOM | 8167 | CZ | PHE | E | 471 | −7.700 | 28.770 | 66.302 | 1.00 | 41.34 | E | C |
| ATOM | 8168 | C | PHE | E | 471 | −3.578 | 26.202 | 61.993 | 1.00 | 33.69 | E | C |
| ATOM | 8169 | O | PHE | E | 471 | −4.347 | 25.589 | 61.250 | 1.00 | 35.68 | E | O |
| ATOM | 8170 | N | LEU | E | 472 | −2.307 | 26.458 | 61.681 | 1.00 | 30.67 | E | N |
| ATOM | 8171 | CA | LEU | E | 472 | −1.712 | 26.041 | 60.414 | 1.00 | 29.59 | E | C |
| ATOM | 8172 | CB | LEU | E | 472 | −1.777 | 27.181 | 59.379 | 1.00 | 29.26 | E | C |
| ATOM | 8173 | CG | LEU | E | 472 | −3.123 | 27.876 | 59.151 | 1.00 | 27.28 | E | C |
| ATOM | 8174 | CD1 | LEU | E | 472 | −2.916 | 29.267 | 58.557 | 1.00 | 26.39 | E | C |
| ATOM | 8175 | CD2 | LEU | E | 472 | −3.961 | 27.020 | 58.229 | 1.00 | 26.15 | E | C |
| ATOM | 8176 | C | LEU | E | 472 | −0.256 | 25.652 | 60.617 | 1.00 | 29.21 | E | C |
| ATOM | 8177 | O | LEU | E | 472 | 0.436 | 26.223 | 61.460 | 1.00 | 30.36 | E | O |
| ATOM | 8178 | N | PRO | E | 473 | 0.232 | 24.672 | 59.841 | 1.00 | 27.45 | E | N |
| ATOM | 8179 | CD | PRO | E | 473 | −0.502 | 23.892 | 58.829 | 1.00 | 23.96 | E | C |
| ATOM | 8180 | CA | PRO | E | 473 | 1.625 | 24.234 | 59.963 | 1.00 | 28.96 | E | C |
| ATOM | 8181 | CB | PRO | E | 473 | 1.589 | 22.806 | 59.442 | 1.00 | 25.25 | E | C |
| ATOM | 8182 | CG | PRO | E | 473 | 0.475 | 22.809 | 58.439 | 1.00 | 23.20 | E | C |
| ATOM | 8183 | C | PRO | E | 473 | 2.601 | 25.100 | 59.160 | 1.00 | 32.53 | E | C |
| ATOM | 8184 | O | PRO | E | 473 | 3.785 | 25.206 | 59.508 | 1.00 | 35.84 | E | O |
| ATOM | 8185 | N | HIS | E | 474 | 2.100 | 25.712 | 58.085 | 1.00 | 32.82 | E | N |
| ATOM | 8186 | CA | HIS | E | 474 | 2.920 | 26.551 | 57.210 | 1.00 | 29.72 | E | C |
| ATOM | 8187 | CB | HIS | E | 474 | 3.841 | 25.662 | 56.382 | 1.00 | 25.66 | E | C |
| ATOM | 8188 | CG | HIS | E | 474 | 3.114 | 24.583 | 55.647 | 1.00 | 25.75 | E | C |
| ATOM | 8189 | CD2 | HIS | E | 474 | 2.062 | 24.640 | 54.795 | 1.00 | 24.97 | E | C |
| ATOM | 8190 | ND1 | HIS | E | 474 | 3.435 | 23.248 | 55.770 | 1.00 | 26.10 | E | N |
| ATOM | 8191 | CE1 | HIS | E | 474 | 2.612 | 22.530 | 55.025 | 1.00 | 25.19 | E | C |
| ATOM | 8192 | NE2 | HIS | E | 474 | 1.770 | 23.350 | 54.424 | 1.00 | 23.21 | E | N |
| ATOM | 8193 | C | HIS | E | 474 | 2.010 | 27.356 | 56.279 | 1.00 | 28.85 | E | C |
| ATOM | 8194 | O | HIS | E | 474 | 0.788 | 27.209 | 56.325 | 1.00 | 27.33 | E | O |
| ATOM | 8195 | N | PHE | E | 475 | 2.610 | 28.185 | 55.426 | 1.00 | 28.91 | E | N |
| ATOM | 8196 | CA | PHE | E | 475 | 1.854 | 29.027 | 54.491 | 1.00 | 27.23 | E | C |
| ATOM | 8197 | CB | PHE | E | 475 | 2.778 | 30.074 | 53.867 | 1.00 | 24.66 | E | C |
| ATOM | 8198 | CG | PHE | E | 475 | 2.055 | 31.161 | 53.117 | 1.00 | 24.91 | E | C |
| ATOM | 8199 | CD1 | PHE | E | 475 | 2.234 | 31.314 | 51.738 | 1.00 | 23.27 | E | C |
| ATOM | 8200 | CD2 | PHE | E | 475 | 1.230 | 32.059 | 53.790 | 1.00 | 23.07 | E | C |
| ATOM | 8201 | CE1 | PHE | E | 475 | 1.606 | 32.348 | 51.039 | 1.00 | 20.96 | E | C |
| ATOM | 8202 | CE2 | PHE | E | 475 | 0.595 | 33.094 | 53.104 | 1.00 | 23.17 | E | C |
| ATOM | 8203 | CZ | PHE | E | 475 | 0.786 | 33.239 | 51.720 | 1.00 | 23.89 | E | C |
| ATOM | 8204 | C | PHE | E | 475 | 1.182 | 28.220 | 53.381 | 1.00 | 26.44 | E | C |
| ATOM | 8205 | O | PHE | E | 475 | 0.087 | 28.566 | 52.922 | 1.00 | 23.82 | E | O |
| ATOM | 8206 | N | GLY | E | 476 | 1.844 | 27.149 | 52.952 | 1.00 | 24.31 | E | N |
| ATOM | 8207 | CA | GLY | E | 476 | 1.291 | 26.317 | 51.899 | 1.00 | 24.63 | E | C |
| ATOM | 8208 | C | GLY | E | 476 | −0.100 | 25.802 | 52.219 | 1.00 | 24.43 | E | C |
| ATOM | 8209 | O | GLY | E | 476 | −0.934 | 25.646 | 51.323 | 1.00 | 23.69 | E | O |
| ATOM | 8210 | N | LYS | E | 477 | −0.365 | 25.544 | 53.496 | 1.00 | 23.74 | E | N |
| ATOM | 8211 | CA | LYS | E | 477 | −1.669 | 25.034 | 53.904 | 1.00 | 20.09 | E | C |
| ATOM | 8212 | CB | LYS | E | 477 | −1.574 | 24.352 | 55.267 | 1.00 | 22.25 | E | C |
| ATOM | 8213 | CG | LYS | E | 477 | −2.907 | 23.839 | 55.790 | 1.00 | 25.48 | E | C |
| ATOM | 8214 | CD | LYS | E | 477 | −3.306 | 22.503 | 55.167 | 1.00 | 26.12 | E | C |
| ATOM | 8215 | CE | LYS | E | 477 | −4.766 | 22.184 | 55.478 | 1.00 | 29.47 | E | C |
| ATOM | 8216 | NZ | LYS | E | 477 | −5.232 | 20.936 | 54.809 | 1.00 | 31.73 | E | N |
| ATOM | 8217 | C | LYS | E | 477 | −2.715 | 26.129 | 53.944 | 1.00 | 19.14 | E | C |
| ATOM | 8218 | O | LYS | E | 477 | −3.911 | 25.847 | 53.942 | 1.00 | 20.82 | E | O |
| ATOM | 8219 | N | MET | E | 478 | −2.274 | 27.383 | 53.988 | 1.00 | 20.46 | E | N |
| ATOM | 8220 | CA | MET | E | 478 | −3.214 | 28.500 | 53.993 | 1.00 | 18.55 | E | C |
| ATOM | 8221 | CB | MET | E | 478 | −2.546 | 29.787 | 54.473 | 1.00 | 19.00 | E | C |
| ATOM | 8222 | CG | MET | E | 478 | −3.535 | 30.922 | 54.692 | 1.00 | 16.52 | E | C |
| ATOM | 8223 | SD | MET | E | 478 | −2.751 | 32.475 | 55.105 | 1.00 | 22.96 | E | S |
| ATOM | 8224 | CE | MET | E | 478 | −4.148 | 33.557 | 55.288 | 1.00 | 17.76 | E | C |
| ATOM | 8225 | C | MET | E | 478 | −3.689 | 28.696 | 52.563 | 1.00 | 20.31 | E | C |
| ATOM | 8226 | O | MET | E | 478 | −4.870 | 28.969 | 52.312 | 1.00 | 17.81 | E | O |
| ATOM | 8227 | N | LEU | E | 479 | −2.750 | 28.555 | 51.630 | 1.00 | 20.20 | E | N |
| ATOM | 8228 | CA | LEU | E | 479 | −3.038 | 28.705 | 50.211 | 1.00 | 20.52 | E | C |
| ATOM | 8229 | CB | LEU | E | 479 | −1.742 | 28.617 | 49.400 | 1.00 | 16.99 | E | C |
| ATOM | 8230 | CG | LEU | E | 479 | −0.811 | 29.832 | 49.386 | 1.00 | 13.26 | E | C |
| ATOM | 8231 | CD1 | LEU | E | 479 | 0.485 | 29.466 | 48.671 | 1.00 | 12.19 | E | C |
| ATOM | 8232 | CD2 | LEU | E | 479 | −1.481 | 30.993 | 48.691 | 1.00 | 11.97 | E | C |
| ATOM | 8233 | C | LEU | E | 479 | −3.988 | 27.585 | 49.800 | 1.00 | 21.63 | E | C |
| ATOM | 8234 | O | LEU | E | 479 | −4.973 | 27.806 | 49.089 | 1.00 | 21.31 | E | O |
| ATOM | 8235 | N | GLU | E | 480 | −3.695 | 26.380 | 50.271 | 1.00 | 24.01 | E | N |
| ATOM | 8236 | CA | GLU | E | 480 | −4.525 | 25.218 | 49.951 | 1.00 | 26.68 | E | C |
| ATOM | 8237 | CB | GLU | E | 480 | −3.928 | 23.956 | 50.582 | 1.00 | 24.28 | E | C |
| ATOM | 8238 | CG | GLU | E | 480 | −4.864 | 22.754 | 50.591 | 1.00 | 30.75 | E | C |
| ATOM | 8239 | CD | GLU | E | 480 | −4.138 | 21.445 | 50.886 | 1.00 | 34.40 | E | C |
| ATOM | 8240 | OE1 | GLU | E | 480 | −2.999 | 21.491 | 51.404 | 1.00 | 35.90 | E | O |
| ATOM | 8241 | OE2 | GLU | E | 480 | −4.704 | 20.368 | 50.599 | 1.00 | 35.33 | E | O |
| ATOM | 8242 | C | GLU | E | 480 | −5.970 | 25.403 | 50.420 | 1.00 | 24.34 | E | C |
| ATOM | 8243 | O | GLU | E | 480 | −6.907 | 25.028 | 49.718 | 1.00 | 24.49 | E | O |
| ATOM | 8244 | N | ASN | E | 481 | −6.144 | 25.980 | 51.606 | 1.00 | 23.68 | E | N |
| ATOM | 8245 | CA | ASN | E | 481 | −7.476 | 26.209 | 52.166 | 1.00 | 20.98 | E | C |
| ATOM | 8246 | CB | ASN | E | 481 | −7.374 | 26.683 | 53.617 | 1.00 | 22.62 | E | C |
| ATOM | 8247 | CG | ASN | E | 481 | −6.958 | 25.582 | 54.566 | 1.00 | 23.39 | E | C |
| ATOM | 8248 | OD1 | ASN | E | 481 | −6.318 | 25.847 | 55.582 | 1.00 | 24.66 | E | O |
| ATOM | 8249 | ND2 | ASN | E | 481 | −7.321 | 24.340 | 54.245 | 1.00 | 23.07 | E | N |
| ATOM | 8250 | C | ASN | E | 481 | −8.228 | 27.261 | 51.375 | 1.00 | 20.27 | E | C |
| ATOM | 8251 | O | ASN | E | 481 | −9.453 | 27.194 | 51.234 | 1.00 | 18.76 | E | O |
| ATOM | 8252 | N | VAL | E | 482 | −7.493 | 28.248 | 50.875 | 1.00 | 18.57 | E | N |
| ATOM | 8253 | CA | VAL | E | 482 | −8.103 | 29.317 | 50.100 | 1.00 | 17.27 | E | C |
| ATOM | 8254 | CB | VAL | E | 482 | −7.142 | 30.533 | 49.958 | 1.00 | 18.82 | E | C |
| ATOM | 8255 | CG1 | VAL | E | 482 | −7.810 | 31.634 | 49.144 | 1.00 | 16.94 | E | C |
| ATOM | 8256 | CG2 | VAL | E | 482 | −6.755 | 31.069 | 51.333 | 1.00 | 16.10 | E | C |
| ATOM | 8257 | C | VAL | E | 482 | −8.505 | 28.856 | 48.699 | 1.00 | 17.29 | E | C |
| ATOM | 8258 | O | VAL | E | 482 | −9.618 | 29.135 | 48.239 | 1.00 | 17.33 | E | O |
| ATOM | 8259 | N | PHE | E | 483 | −7.623 | 28.118 | 48.033 | 1.00 | 16.15 | E | N |
| ATOM | 8260 | CA | PHE | E | 483 | −7.904 | 27.702 | 46.666 | 1.00 | 18.60 | E | C |
| ATOM | 8261 | CB | PHE | E | 483 | −6.680 | 28.002 | 45.801 | 1.00 | 17.40 | E | C |
| ATOM | 8262 | CG | PHE | E | 483 | −6.324 | 29.458 | 45.751 | 1.00 | 14.49 | E | C |
| ATOM | 8263 | CD1 | PHE | E | 483 | −7.133 | 30.361 | 45.078 | 1.00 | 12.28 | E | C |
| ATOM | 8264 | CD2 | PHE | E | 483 | −5.195 | 29.930 | 46.407 | 1.00 | 14.70 | E | C |
| ATOM | 8265 | CE1 | PHE | E | 483 | −6.824 | 31.712 | 45.061 | 1.00 | 12.97 | E | C |
| ATOM | 8266 | CE2 | PHE | E | 483 | −4.879 | 31.280 | 46.395 | 1.00 | 12.94 | E | C |
| ATOM | 8267 | CZ | PHE | E | 483 | −5.696 | 32.173 | 45.723 | 1.00 | 13.30 | E | C |
| ATOM | 8268 | C | PHE | E | 483 | −8.397 | 26.292 | 46.355 | 1.00 | 19.61 | E | C |
| ATOM | 8269 | O | PHE | E | 483 | −9.207 | 26.117 | 45.445 | 1.00 | 18.96 | E | O |
| ATOM | 8270 | N | MET | E | 484 | −7.919 | 25.288 | 47.078 | 1.00 | 22.17 | E | N |
| ATOM | 8271 | CA | MET | E | 484 | −8.333 | 23.913 | 46.798 | 1.00 | 24.24 | E | C |
| ATOM | 8272 | CB | MET | E | 484 | −7.733 | 22.961 | 47.838 | 1.00 | 27.64 | E | C |
| ATOM | 8273 | CG | MET | E | 484 | −7.862 | 21.483 | 47.480 | 1.00 | 31.59 | E | C |
| ATOM | 8274 | SD | MET | E | 484 | −6.956 | 21.000 | 45.994 | 1.00 | 37.76 | E | S |
| ATOM | 8275 | CE | MET | E | 484 | −5.300 | 20.745 | 46.642 | 1.00 | 33.63 | E | C |
| ATOM | 8276 | C | MET | E | 484 | −9.852 | 23.704 | 46.715 | 1.00 | 23.74 | E | C |
| ATOM | 8277 | O | MET | E | 484 | −10.356 | 23.124 | 45.752 | 1.00 | 25.18 | E | O |
| ATOM | 8278 | N | PRO | E | 485 | −10.605 | 24.168 | 47.721 | 1.00 | 24.36 | E | N |
| ATOM | 8279 | CD | PRO | E | 485 | −10.186 | 24.859 | 48.951 | 1.00 | 24.40 | E | C |
| ATOM | 8280 | CA | PRO | E | 485 | −12.058 | 23.981 | 47.672 | 1.00 | 24.77 | E | C |
| ATOM | 8281 | CB | PRO | E | 485 | −12.556 | 24.650 | 48.955 | 1.00 | 22.16 | E | C |
| ATOM | 8282 | CG | PRO | E | 485 | −11.368 | 24.672 | 49.854 | 1.00 | 23.42 | E | C |
| ATOM | 8283 | C | PRO | E | 485 | −12.734 | 24.558 | 46.431 | 1.00 | 25.62 | E | C |
| ATOM | 8284 | O | PRO | E | 485 | −13.745 | 24.021 | 45.967 | 1.00 | 24.81 | E | O |
| ATOM | 8285 | N | VAL | E | 486 | −12.186 | 25.652 | 45.901 | 1.00 | 25.28 | E | N |
| ATOM | 8286 | CA | VAL | E | 486 | −12.762 | 26.281 | 44.717 | 1.00 | 23.27 | E | C |
| ATOM | 8287 | CB | VAL | E | 486 | −12.257 | 27.716 | 44.544 | 1.00 | 23.13 | E | C |
| ATOM | 8288 | CG1 | VAL | E | 486 | −13.277 | 28.518 | 43.773 | 1.00 | 24.07 | E | C |
| ATOM | 8289 | CG2 | VAL | E | 486 | −12.023 | 28.352 | 45.896 | 1.00 | 24.86 | E | C |
| ATOM | 8290 | C | VAL | E | 486 | −12.444 | 25.483 | 43.454 | 1.00 | 22.63 | E | C |
| ATOM | 8291 | O | VAL | E | 486 | −13.270 | 25.392 | 42.545 | 1.00 | 24.07 | E | O |
| ATOM | 8292 | N | PHE | E | 487 | −11.246 | 24.915 | 43.399 | 1.00 | 20.85 | E | N |
| ATOM | 8293 | CA | PHE | E | 487 | −10.838 | 24.101 | 42.263 | 1.00 | 21.71 | E | C |
| ATOM | 8294 | CB | PHE | E | 487 | −9.380 | 23.668 | 42.412 | 1.00 | 20.65 | E | C |
| ATOM | 8295 | CG | PHE | E | 487 | −8.394 | 24.638 | 41.824 | 1.00 | 22.46 | E | C |
| ATOM | 8296 | CD1 | PHE | E | 487 | −7.923 | 25.711 | 42.572 | 1.00 | 24.17 | E | C |
| ATOM | 8297 | CD2 | PHE | E | 487 | −7.941 | 24.485 | 40.516 | 1.00 | 25.10 | E | C |
| ATOM | 8298 | CE1 | PHE | E | 487 | −7.010 | 26.626 | 42.025 | 1.00 | 22.54 | E | C |
| ATOM | 8299 | CE2 | PHE | E | 487 | −7.032 | 25.390 | 39.959 | 1.00 | 23.97 | E | C |
| ATOM | 8300 | CZ | PHE | E | 487 | −6.567 | 26.462 | 40.717 | 1.00 | 22.70 | E | C |
| ATOM | 8301 | C | PHE | E | 487 | −11.733 | 22.866 | 42.242 | 1.00 | 24.09 | E | C |
| ATOM | 8302 | O | PHE | E | 487 | −12.262 | 22.480 | 41.199 | 1.00 | 23.77 | E | O |
| ATOM | 8303 | N | GLU | E | 488 | −11.908 | 22.262 | 43.414 | 1.00 | 25.58 | E | N |
| ATOM | 8304 | CA | GLU | E | 488 | −12.735 | 21.072 | 43.558 | 1.00 | 27.39 | E | C |
| ATOM | 8305 | CB | GLU | E | 488 | −12.775 | 20.629 | 45.025 | 1.00 | 32.60 | E | C |
| ATOM | 8306 | CG | GLU | E | 488 | −11.911 | 19.412 | 45.337 | 1.00 | 37.11 | E | C |
| ATOM | 8307 | CD | GLU | E | 488 | −11.330 | 19.449 | 46.749 | 1.00 | 43.18 | E | C |
| ATOM | 8308 | OE1 | GLU | E | 488 | −11.878 | 20.181 | 47.609 | 1.00 | 44.72 | E | O |
| ATOM | 8309 | OE2 | GLU | E | 488 | −10.324 | 18.742 | 47.000 | 1.00 | 42.94 | E | O |
| ATOM | 8310 | C | GLU | E | 488 | −14.159 | 21.286 | 43.056 | 1.00 | 24.85 | E | C |
| ATOM | 8311 | O | GLU | E | 488 | −14.725 | 20.414 | 42.409 | 1.00 | 26.88 | E | O |
| ATOM | 8312 | N | ALA | E | 489 | −14.743 | 22.440 | 43.356 | 1.00 | 22.33 | E | N |
| ATOM | 8313 | CA | ALA | E | 489 | −16.105 | 22.729 | 42.912 | 1.00 | 21.57 | E | C |
| ATOM | 8314 | CB | ALA | E | 489 | −16.671 | 23.894 | 43.704 | 1.00 | 18.11 | E | C |
| ATOM | 8315 | C | ALA | E | 489 | −16.144 | 23.041 | 41.412 | 1.00 | 24.48 | E | C |
| ATOM | 8316 | O | ALA | E | 489 | −17.208 | 22.999 | 40.783 | 1.00 | 22.27 | E | O |
| ATOM | 8317 | N | THR | E | 490 | −14.981 | 23.359 | 40.847 | 1.00 | 24.68 | E | N |
| ATOM | 8318 | CA | THR | E | 490 | −14.865 | 23.681 | 39.428 | 1.00 | 26.80 | E | C |
| ATOM | 8319 | CB | THR | E | 490 | −13.562 | 24.481 | 39.142 | 1.00 | 26.10 | E | C |
| ATOM | 8320 | OG1 | THR | E | 490 | −13.696 | 25.810 | 39.659 | 1.00 | 30.61 | E | O |
| ATOM | 8321 | CG2 | THR | E | 490 | −13.288 | 24.565 | 37.648 | 1.00 | 23.30 | E | C |
| ATOM | 8322 | C | THR | E | 490 | −14.832 | 22.383 | 38.625 | 1.00 | 29.06 | E | C |
| ATOM | 8323 | O | THR | E | 490 | −15.508 | 22.237 | 37.605 | 1.00 | 27.24 | E | O |
| ATOM | 8324 | N | ILE | E | 491 | −14.036 | 21.440 | 39.108 | 1.00 | 29.88 | E | N |
| ATOM | 8325 | CA | ILE | E | 491 | −13.883 | 20.147 | 38.471 | 1.00 | 28.69 | E | C |
| ATOM | 8326 | CB | ILE | E | 491 | −12.634 | 19.448 | 39.040 | 1.00 | 30.04 | E | C |
| ATOM | 8327 | CG2 | ILE | E | 491 | −12.944 | 18.036 | 39.477 | 1.00 | 33.60 | E | C |
| ATOM | 8328 | CG1 | ILE | E | 491 | −11.527 | 19.471 | 37.998 | 1.00 | 28.92 | E | C |
| ATOM | 8329 | CD1 | ILE | E | 491 | −10.415 | 20.409 | 38.358 | 1.00 | 31.35 | E | C |
| ATOM | 8330 | C | ILE | E | 491 | −15.129 | 19.271 | 38.648 | 1.00 | 30.39 | E | C |
| ATOM | 8331 | O | ILE | E | 491 | −15.576 | 18.629 | 37.700 | 1.00 | 32.22 | E | O |
| ATOM | 8332 | N | ASN | E | 492 | −15.692 | 19.255 | 39.855 | 1.00 | 28.45 | E | N |
| ATOM | 8333 | CA | ASN | E | 492 | −16.880 | 18.448 | 40.146 | 1.00 | 25.98 | E | C |
| ATOM | 8334 | CB | ASN | E | 492 | −16.529 | 17.363 | 41.165 | 1.00 | 25.94 | E | C |
| ATOM | 8335 | CG | ASN | E | 492 | −15.398 | 16.462 | 40.688 | 1.00 | 28.42 | E | C |
| ATOM | 8336 | OD1 | ASN | E | 492 | −15.455 | 15.904 | 39.589 | 1.00 | 25.92 | E | O |
| ATOM | 8337 | ND2 | ASN | E | 492 | −14.359 | 16.317 | 41.515 | 1.00 | 28.17 | E | N |
| ATOM | 8338 | C | ASN | E | 492 | −18.025 | 19.306 | 40.682 | 1.00 | 25.69 | E | C |
| ATOM | 8339 | O | ASN | E | 492 | −18.394 | 19.209 | 41.849 | 1.00 | 25.53 | E | O |
| ATOM | 8340 | N | PRO | E | 493 | −18.618 | 20.140 | 39.819 | 1.00 | 25.58 | E | N |
| ATOM | 8341 | CD | PRO | E | 493 | −18.279 | 20.290 | 38.394 | 1.00 | 25.33 | E | C |
| ATOM | 8342 | CA | PRO | E | 493 | −19.721 | 21.023 | 40.213 | 1.00 | 25.79 | E | C |
| ATOM | 8343 | CB | PRO | E | 493 | −20.036 | 21.809 | 38.937 | 1.00 | 24.57 | E | C |
| ATOM | 8344 | CG | PRO | E | 493 | −18.840 | 21.638 | 38.061 | 1.00 | 25.30 | E | C |
| ATOM | 8345 | C | PRO | E | 493 | −20.960 | 20.331 | 40.770 | 1.00 | 26.31 | E | C |
| ATOM | 8346 | O | PRO | E | 493 | −21.738 | 20.939 | 41.506 | 1.00 | 26.67 | E | O |
| ATOM | 8347 | N | GLN | E | 494 | −21.159 | 19.069 | 40.417 | 1.00 | 26.93 | E | N |
| ATOM | 8348 | CA | GLN | E | 494 | −22.328 | 18.351 | 40.904 | 1.00 | 31.36 | E | C |
| ATOM | 8349 | CB | GLN | E | 494 | −22.621 | 17.155 | 40.003 | 1.00 | 34.43 | E | C |
| ATOM | 8350 | CG | GLN | E | 494 | −22.789 | 17.536 | 38.546 | 1.00 | 40.35 | E | C |
| ATOM | 8351 | CD | GLN | E | 494 | −24.174 | 18.064 | 38.232 | 1.00 | 42.02 | E | C |
| ATOM | 8352 | OE1 | GLN | E | 494 | −24.655 | 17.917 | 37.114 | 1.00 | 49.26 | E | O |
| ATOM | 8353 | NE2 | GLN | E | 494 | −24.822 | 18.679 | 39.216 | 1.00 | 40.76 | E | N |
| ATOM | 8354 | C | GLN | E | 494 | −22.128 | 17.885 | 42.341 | 1.00 | 32.82 | E | C |
| ATOM | 8355 | O | GLN | E | 494 | −23.089 | 17.735 | 43.099 | 1.00 | 31.95 | E | O |
| ATOM | 8356 | N | ALA | E | 495 | −20.871 | 17.661 | 42.709 | 1.00 | 31.49 | E | N |
| ATOM | 8357 | CA | ALA | E | 495 | −20.535 | 17.223 | 44.055 | 1.00 | 29.49 | E | C |
| ATOM | 8358 | CB | ALA | E | 495 | −19.128 | 16.657 | 44.072 | 1.00 | 26.90 | E | C |
| ATOM | 8359 | C | ALA | E | 495 | −20.641 | 18.404 | 45.014 | 1.00 | 29.09 | E | C |
| ATOM | 8360 | O | ALA | E | 495 | −20.956 | 18.237 | 46.190 | 1.00 | 29.34 | E | O |
| ATOM | 8361 | N | HIS | E | 496 | −20.383 | 19.601 | 44.495 | 1.00 | 29.28 | E | N |
| ATOM | 8362 | CA | HIS | E | 496 | −20.435 | 20.827 | 45.291 | 1.00 | 26.78 | E | C |
| ATOM | 8363 | CB | HIS | E | 496 | −19.027 | 21.410 | 45.423 | 1.00 | 25.66 | E | C |
| ATOM | 8364 | CG | HIS | E | 496 | −17.992 | 20.394 | 45.793 | 1.00 | 27.47 | E | C |
| ATOM | 8365 | CD2 | HIS | E | 496 | −16.923 | 19.916 | 45.112 | 1.00 | 30.55 | E | C |
| ATOM | 8366 | ND1 | HIS | E | 496 | −17.999 | 19.732 | 47.004 | 1.00 | 30.66 | E | N |
| ATOM | 8367 | CE1 | HIS | E | 496 | −16.979 | 18.892 | 47.049 | 1.00 | 30.66 | E | C |
| ATOM | 8368 | NE2 | HIS | E | 496 | −16.311 | 18.984 | 45.916 | 1.00 | 29.24 | E | N |
| ATOM | 8369 | C | HIS | E | 496 | −21.371 | 21.850 | 44.650 | 1.00 | 25.06 | E | C |
| ATOM | 8370 | O | HIS | E | 496 | −20.943 | 22.909 | 44.205 | 1.00 | 23.93 | E | O |
| ATOM | 8371 | N | PRO | E | 497 | −22.670 | 21.536 | 44.592 | 1.00 | 24.32 | E | N |
| ATOM | 8372 | CD | PRO | E | 497 | −23.263 | 20.279 | 45.076 | 1.00 | 23.20 | E | C |
| ATOM | 8373 | CA | PRO | E | 497 | −23.679 | 22.420 | 44.002 | 1.00 | 24.09 | E | C |
| ATOM | 8374 | CB | PRO | E | 497 | −24.979 | 21.624 | 44.128 | 1.00 | 23.69 | E | C |
| ATOM | 8375 | CG | PRO | E | 497 | −24.712 | 20.619 | 45.192 | 1.00 | 22.43 | E | C |
| ATOM | 8376 | C | PRO | E | 497 | −23.818 | 23.812 | 44.606 | 1.00 | 26.08 | E | C |
| ATOM | 8377 | O | PRO | E | 497 | −23.846 | 24.801 | 43.874 | 1.00 | 28.51 | E | O |
| ATOM | 8378 | N | GLU | E | 498 | −23.928 | 23.895 | 45.932 | 1.00 | 27.82 | E | N |
| ATOM | 8379 | CA | GLU | E | 498 | −24.091 | 25.186 | 46.608 | 1.00 | 22.75 | E | C |
| ATOM | 8380 | CB | GLU | E | 498 | −24.352 | 24.978 | 48.101 | 1.00 | 23.08 | E | C |
| ATOM | 8381 | CG | GLU | E | 498 | −25.638 | 25.638 | 48.583 | 1.00 | 27.54 | E | C |
| ATOM | 8382 | CD | GLU | E | 498 | −25.941 | 25.374 | 50.056 | 1.00 | 32.75 | E | C |
| ATOM | 8383 | OE1 | GLU | E | 498 | −25.026 | 24.972 | 50.810 | 1.00 | 33.67 | E | O |
| ATOM | 8384 | OE2 | GLU | E | 498 | −27.107 | 25.570 | 50.463 | 1.00 | 35.24 | E | O |
| ATOM | 8385 | C | GLU | E | 498 | −22.883 | 26.093 | 46.411 | 1.00 | 20.88 | E | C |
| ATOM | 8386 | O | GLU | E | 498 | −23.024 | 27.290 | 46.151 | 1.00 | 20.19 | E | O |
| ATOM | 8387 | N | LEU | E | 499 | −21.693 | 25.522 | 46.530 | 1.00 | 19.43 | E | N |
| ATOM | 8388 | CA | LEU | E | 499 | −20.480 | 26.298 | 46.346 | 1.00 | 19.75 | E | C |
| ATOM | 8389 | CB | LEU | E | 499 | −19.256 | 25.460 | 46.734 | 1.00 | 14.85 | E | C |
| ATOM | 8390 | CG | LEU | E | 499 | −17.887 | 26.092 | 46.469 | 1.00 | 17.03 | E | C |
| ATOM | 8391 | CD1 | LEU | E | 499 | −17.847 | 27.515 | 47.019 | 1.00 | 13.14 | E | C |
| ATOM | 8392 | CD2 | LEU | E | 499 | −16.808 | 25.233 | 47.108 | 1.00 | 14.87 | E | C |
| ATOM | 8393 | C | LEU | E | 499 | −20.386 | 26.735 | 44.881 | 1.00 | 19.22 | E | C |
| ATOM | 8394 | O | LEU | E | 499 | −20.003 | 27.860 | 44.584 | 1.00 | 20.53 | E | O |
| ATOM | 8395 | N | SER | E | 500 | −20.748 | 25.834 | 43.975 | 1.00 | 19.09 | E | N |
| ATOM | 8396 | CA | SER | E | 500 | −20.707 | 26.112 | 42.541 | 1.00 | 21.05 | E | C |
| ATOM | 8397 | CB | SER | E | 500 | −21.199 | 24.893 | 41.745 | 1.00 | 19.96 | E | C |
| ATOM | 8398 | OG | SER | E | 500 | −20.225 | 23.860 | 41.720 | 1.00 | 19.88 | E | O |
| ATOM | 8399 | C | SER | E | 500 | −21.574 | 27.315 | 42.203 | 1.00 | 22.46 | E | C |
| ATOM | 8400 | O | SER | E | 500 | −21.177 | 28.184 | 41.424 | 1.00 | 23.85 | E | O |
| ATOM | 8401 | N | VAL | E | 501 | −22.766 | 27.359 | 42.788 | 1.00 | 21.42 | E | N |
| ATOM | 8402 | CA | VAL | E | 501 | −23.694 | 28.454 | 42.547 | 1.00 | 20.88 | E | C |
| ATOM | 8403 | CB | VAL | E | 501 | −25.058 | 28.157 | 43.197 | 1.00 | 18.64 | E | C |
| ATOM | 8404 | CG1 | VAL | E | 501 | −25.863 | 29.436 | 43.360 | 1.00 | 18.25 | E | C |
| ATOM | 8405 | CG2 | VAL | E | 501 | −25.812 | 27.162 | 42.350 | 1.00 | 15.62 | E | C |
| ATOM | 8406 | C | VAL | E | 501 | −23.122 | 29.749 | 43.121 | 1.00 | 23.38 | E | C |
| ATOM | 8407 | O | VAL | E | 501 | −23.169 | 30.803 | 42.486 | 1.00 | 23.62 | E | O |
| ATOM | 8408 | N | PHE | E | 502 | −22.575 | 29.657 | 44.327 | 1.00 | 23.42 | E | N |
| ATOM | 8409 | CA | PHE | E | 502 | −21.995 | 30.810 | 44.995 | 1.00 | 21.51 | E | C |
| ATOM | 8410 | CB | PHE | E | 502 | −21.422 | 30.371 | 46.355 | 1.00 | 22.03 | E | C |
| ATOM | 8411 | CG | PHE | E | 502 | −20.766 | 31.480 | 47.144 | 1.00 | 15.40 | E | C |
| ATOM | 8412 | CD1 | PHE | E | 502 | −21.446 | 32.656 | 47.417 | 1.00 | 14.32 | E | C |
| ATOM | 8413 | CD2 | PHE | E | 502 | −19.470 | 31.334 | 47.620 | 1.00 | 13.31 | E | C |
| ATOM | 8414 | CE1 | PHE | E | 502 | −20.840 | 33.674 | 48.155 | 1.00 | 14.50 | E | C |
| ATOM | 8415 | CE2 | PHE | E | 502 | −18.857 | 32.345 | 48.357 | 1.00 | 11.96 | E | C |
| ATOM | 8416 | CZ | PHE | E | 502 | −19.542 | 33.514 | 48.625 | 1.00 | 11.42 | E | C |
| ATOM | 8417 | C | PHE | E | 502 | −20.905 | 31.420 | 44.110 | 1.00 | 21.08 | E | C |
| ATOM | 8418 | O | PHE | E | 502 | −20.888 | 32.631 | 43.878 | 1.00 | 20.50 | E | O |
| ATOM | 8419 | N | LEU | E | 503 | −20.011 | 30.572 | 43.610 | 1.00 | 19.81 | E | N |
| ATOM | 8420 | CA | LEU | E | 503 | −18.909 | 31.007 | 42.754 | 1.00 | 18.07 | E | C |
| ATOM | 8421 | CB | LEU | E | 503 | −18.090 | 29.801 | 42.312 | 1.00 | 14.19 | E | C |
| ATOM | 8422 | CG | LEU | E | 503 | −17.251 | 29.176 | 43.424 | 1.00 | 13.54 | E | C |
| ATOM | 8423 | CD1 | LEU | E | 503 | −16.556 | 27.933 | 42.903 | 1.00 | 9.72 | E | C |
| ATOM | 8424 | CD2 | LEU | E | 503 | −16.237 | 30.194 | 43.925 | 1.00 | 11.43 | E | C |
| ATOM | 8425 | C | LEU | E | 503 | −19.348 | 31.801 | 41.528 | 1.00 | 17.93 | E | C |
| ATOM | 8426 | O | LEU | E | 503 | −18.556 | 32.535 | 40.949 | 1.00 | 21.14 | E | O |
| ATOM | 8427 | N | LYS | E | 504 | −20.601 | 31.654 | 41.122 | 1.00 | 19.14 | E | N |
| ATOM | 8428 | CA | LYS | E | 504 | −21.104 | 32.395 | 39.973 | 1.00 | 19.62 | E | C |
| ATOM | 8429 | CB | LYS | E | 504 | −22.390 | 31.761 | 39.448 | 1.00 | 17.72 | E | C |
| ATOM | 8430 | CG | LYS | E | 504 | −22.150 | 30.541 | 38.602 | 1.00 | 19.80 | E | C |
| ATOM | 8431 | CD | LYS | E | 504 | −23.434 | 29.787 | 38.353 | 1.00 | 25.81 | E | C |
| ATOM | 8432 | CE | LYS | E | 504 | −24.302 | 30.487 | 37.327 | 1.00 | 26.88 | E | C |
| ATOM | 8433 | NZ | LYS | E | 504 | −25.668 | 29.894 | 37.318 | 1.00 | 32.68 | E | N |
| ATOM | 8434 | C | LYS | E | 504 | −21.395 | 33.829 | 40.384 | 1.00 | 20.83 | E | C |
| ATOM | 8435 | O | LYS | E | 504 | −21.611 | 34.691 | 39.532 | 1.00 | 21.16 | E | O |
| ATOM | 8436 | N | HIS | E | 505 | −21.399 | 34.073 | 41.695 | 1.00 | 20.25 | E | N |
| ATOM | 8437 | CA | HIS | E | 505 | −21.685 | 35.392 | 42.248 | 1.00 | 15.06 | E | C |
| ATOM | 8438 | CB | HIS | E | 505 | −22.642 | 35.262 | 43.432 | 1.00 | 14.32 | E | C |
| ATOM | 8439 | CG | HIS | E | 505 | −24.026 | 34.848 | 43.041 | 1.00 | 17.05 | E | C |
| ATOM | 8440 | CD2 | HIS | E | 505 | −24.534 | 33.637 | 42.711 | 1.00 | 17.50 | E | C |
| ATOM | 8441 | ND1 | HIS | E | 505 | −25.072 | 35.739 | 42.954 | 1.00 | 18.95 | E | N |
| ATOM | 8442 | CE1 | HIS | E | 505 | −26.166 | 35.097 | 42.585 | 1.00 | 17.33 | E | C |
| ATOM | 8443 | NE2 | HIS | E | 505 | −25.867 | 33.819 | 42.431 | 1.00 | 16.43 | E | N |
| ATOM | 8444 | C | HIS | E | 505 | −20.448 | 36.160 | 42.688 | 1.00 | 15.29 | E | C |
| ATOM | 8445 | O | HIS | E | 505 | −20.543 | 37.336 | 43.031 | 1.00 | 16.68 | E | O |
| ATOM | 8446 | N | ILE | E | 506 | −19.295 | 35.494 | 42.683 | 1.00 | 14.48 | E | N |
| ATOM | 8447 | CA | ILE | E | 506 | −18.031 | 36.118 | 43.076 | 1.00 | 15.43 | E | C |
| ATOM | 8448 | CB | ILE | E | 506 | −17.088 | 35.099 | 43.769 | 1.00 | 11.27 | E | C |
| ATOM | 8449 | CG2 | ILE | E | 506 | −15.735 | 35.724 | 44.027 | 1.00 | 8.82 | E | C |
| ATOM | 8450 | CG1 | ILE | E | 506 | −17.715 | 34.611 | 45.080 | 1.00 | 11.69 | E | C |
| ATOM | 8451 | CD1 | ILE | E | 506 | −18.206 | 35.716 | 46.010 | 1.00 | 10.17 | E | C |
| ATOM | 8452 | C | ILE | E | 506 | −17.350 | 36.649 | 41.819 | 1.00 | 17.69 | E | C |
| ATOM | 8453 | O | ILE | E | 506 | −17.099 | 35.890 | 40.873 | 1.00 | 17.12 | E | O |
| ATOM | 8454 | N | THR | E | 507 | −17.056 | 37.951 | 41.814 | 1.00 | 16.30 | E | N |
| ATOM | 8455 | CA | THR | E | 507 | −16.431 | 38.603 | 40.669 | 1.00 | 12.46 | E | C |
| ATOM | 8456 | CB | THR | E | 507 | −17.018 | 40.034 | 40.460 | 1.00 | 11.26 | E | C |
| ATOM | 8457 | OG1 | THR | E | 507 | −16.580 | 40.907 | 41.510 | 1.00 | 13.62 | E | O |
| ATOM | 8458 | CG2 | THR | E | 507 | −18.530 | 39.993 | 40.469 | 1.00 | 7.64 | E | C |
| ATOM | 8459 | C | THR | E | 507 | −14.905 | 38.680 | 40.766 | 1.00 | 13.93 | E | C |
| ATOM | 8460 | O | THR | E | 507 | −14.214 | 38.712 | 39.744 | 1.00 | 11.39 | E | O |
| ATOM | 8461 | N | GLY | E | 508 | −14.371 | 38.697 | 41.986 | 1.00 | 13.70 | E | N |
| ATOM | 8462 | CA | GLY | E | 508 | −12.928 | 38.773 | 42.136 | 1.00 | 11.29 | E | C |
| ATOM | 8463 | C | GLY | E | 508 | −12.393 | 38.554 | 43.536 | 1.00 | 14.23 | E | C |
| ATOM | 8464 | O | GLY | E | 508 | −13.154 | 38.380 | 44.495 | 1.00 | 11.69 | E | O |
| ATOM | 8465 | N | PHE | E | 509 | −11.065 | 38.567 | 43.645 | 1.00 | 15.12 | E | N |
| ATOM | 8466 | CA | PHE | E | 509 | −10.374 | 38.376 | 44.918 | 1.00 | 15.71 | E | C |
| ATOM | 8467 | CB | PHE | E | 509 | −9.369 | 37.237 | 44.798 | 1.00 | 16.10 | E | C |
| ATOM | 8468 | CG | PHE | E | 509 | −10.002 | 35.884 | 44.754 | 1.00 | 18.98 | E | C |
| ATOM | 8469 | CD1 | PHE | E | 509 | −10.161 | 35.142 | 45.920 | 1.00 | 17.97 | E | C |
| ATOM | 8470 | CD2 | PHE | E | 509 | −10.466 | 35.358 | 43.550 | 1.00 | 19.26 | E | C |
| ATOM | 8471 | CE1 | PHE | E | 509 | −10.775 | 33.890 | 45.893 | 1.00 | 19.46 | E | C |
| ATOM | 8472 | CE2 | PHE | E | 509 | −11.083 | 34.106 | 43.509 | 1.00 | 19.74 | E | C |
| ATOM | 8473 | CZ | PHE | E | 509 | −11.239 | 33.370 | 44.686 | 1.00 | 19.79 | E | C |
| ATOM | 8474 | C | PHE | E | 509 | −9.644 | 39.632 | 45.385 | 1.00 | 16.84 | E | C |
| ATOM | 8475 | O | PHE | E | 509 | −9.107 | 40.388 | 44.569 | 1.00 | 16.70 | E | O |
| ATOM | 8476 | N | ASP | E | 510 | −9.628 | 39.838 | 46.703 | 1.00 | 17.16 | E | N |
| ATOM | 8477 | CA | ASP | E | 510 | −8.968 | 40.985 | 47.323 | 1.00 | 13.81 | E | C |
| ATOM | 8478 | CB | ASP | E | 510 | −10.016 | 41.910 | 47.949 | 1.00 | 11.11 | E | C |
| ATOM | 8479 | CG | ASP | E | 510 | −9.497 | 43.315 | 48.180 | 1.00 | 12.23 | E | C |
| ATOM | 8480 | OD1 | ASP | E | 510 | −8.263 | 43.509 | 48.174 | 1.00 | 17.97 | E | O |
| ATOM | 8481 | OD2 | ASP | E | 510 | −10.319 | 44.233 | 48.369 | 1.00 | 13.33 | E | O |
| ATOM | 8482 | C | ASP | E | 510 | −7.996 | 40.493 | 48.399 | 1.00 | 15.20 | E | C |
| ATOM | 8483 | O | ASP | E | 510 | −8.138 | 39.385 | 48.912 | 1.00 | 15.51 | E | O |
| ATOM | 8484 | N | SER | E | 511 | −7.004 | 41.312 | 48.729 | 1.00 | 15.92 | E | N |
| ATOM | 8485 | CA | SER | E | 511 | −6.016 | 40.973 | 49.752 | 1.00 | 17.76 | E | C |
| ATOM | 8486 | CB | SER | E | 511 | −4.659 | 40.726 | 49.094 | 1.00 | 16.93 | E | C |
| ATOM | 8487 | OG | SER | E | 511 | −3.590 | 41.028 | 49.966 | 1.00 | 16.68 | E | O |
| ATOM | 8488 | C | SER | E | 511 | −5.948 | 42.159 | 50.720 | 1.00 | 19.83 | E | C |
| ATOM | 8489 | O | SER | E | 511 | −5.529 | 43.247 | 50.348 | 1.00 | 19.42 | E | O |
| ATOM | 8490 | N | VAL | E | 512 | −6.363 | 41.934 | 51.962 | 1.00 | 23.73 | E | N |
| ATOM | 8491 | CA | VAL | E | 512 | −6.414 | 42.987 | 52.979 | 1.00 | 23.42 | E | C |
| ATOM | 8492 | CB | VAL | E | 512 | −7.861 | 43.161 | 53.450 | 1.00 | 21.78 | E | C |
| ATOM | 8493 | CG1 | VAL | E | 512 | −8.785 | 43.303 | 52.244 | 1.00 | 18.49 | E | C |
| ATOM | 8494 | CG2 | VAL | E | 512 | −8.283 | 41.945 | 54.251 | 1.00 | 21.45 | E | C |
| ATOM | 8495 | C | VAL | E | 512 | −5.527 | 42.729 | 54.201 | 1.00 | 27.23 | E | C |
| ATOM | 8496 | O | VAL | E | 512 | −5.007 | 41.627 | 54.381 | 1.00 | 26.02 | E | O |
| ATOM | 8497 | N | ASP | E | 513 | −5.378 | 43.748 | 55.048 | 1.00 | 32.68 | E | N |
| ATOM | 8498 | CA | ASP | E | 513 | −4.544 | 43.676 | 56.262 | 1.00 | 36.47 | E | C |
| ATOM | 8499 | CB | ASP | E | 513 | −3.490 | 42.532 | 56.173 | 1.00 | 40.85 | E | C |
| ATOM | 8500 | CG | ASP | E | 513 | −2.483 | 42.514 | 57.372 | 1.00 | 44.35 | E | C |
| ATOM | 8501 | OD1 | ASP | E | 513 | −2.913 | 42.718 | 58.538 | 1.00 | 44.48 | E | O |
| ATOM | 8502 | OD2 | ASP | E | 513 | −1.260 | 42.285 | 57.148 | 1.00 | 39.15 | E | O |
| ATOM | 8503 | C | ASP | E | 513 | −3.802 | 44.995 | 56.372 | 1.00 | 33.24 | E | C |
| ATOM | 8504 | O | ASP | E | 513 | −3.911 | 45.858 | 55.507 | 1.00 | 32.80 | E | O |
| ATOM | 8505 | N | ASP | E | 514 | −3.050 | 45.146 | 57.449 | 1.00 | 31.72 | E | N |
| ATOM | 8506 | CA | ASP | E | 514 | −2.254 | 46.334 | 57.640 | 1.00 | 28.85 | E | C |
| ATOM | 8507 | CB | ASP | E | 514 | −1.558 | 46.264 | 58.996 | 1.00 | 27.47 | E | C |
| ATOM | 8508 | CG | ASP | E | 514 | −0.892 | 47.557 | 59.369 | 1.00 | 28.93 | E | C |
| ATOM | 8509 | OD1 | ASP | E | 514 | −0.668 | 48.395 | 58.474 | 1.00 | 27.69 | E | O |
| ATOM | 8510 | OD2 | ASP | E | 514 | −0.596 | 47.733 | 60.565 | 1.00 | 33.75 | E | O |
| ATOM | 8511 | C | ASP | E | 514 | −1.232 | 46.247 | 56.517 | 1.00 | 27.72 | E | C |
| ATOM | 8512 | O | ASP | E | 514 | −0.729 | 45.161 | 56.229 | 1.00 | 30.47 | E | O |
| ATOM | 8513 | N | GLU | E | 515 | −0.938 | 47.367 | 55.869 | 1.00 | 26.43 | E | N |
| ATOM | 8514 | CA | GLU | E | 515 | 0.046 | 47.373 | 54.789 | 1.00 | 24.42 | E | C |
| ATOM | 8515 | CB | GLU | E | 515 | −0.505 | 48.108 | 53.559 | 1.00 | 20.79 | E | C |
| ATOM | 8516 | CG | GLU | E | 515 | −0.148 | 47.449 | 52.230 | 1.00 | 17.07 | E | C |
| ATOM | 8517 | CD | GLU | E | 515 | −0.370 | 48.357 | 51.022 | 1.00 | 16.52 | E | C |
| ATOM | 8518 | OE1 | GLU | E | 515 | −1.364 | 49.117 | 51.002 | 1.00 | 13.01 | E | O |
| ATOM | 8519 | OE2 | GLU | E | 515 | 0.454 | 48.305 | 50.084 | 1.00 | 13.05 | E | O |
| ATOM | 8520 | C | GLU | E | 515 | 1.324 | 48.052 | 55.261 | 1.00 | 24.63 | E | C |
| ATOM | 8521 | O | GLU | E | 515 | 2.375 | 47.914 | 54.637 | 1.00 | 22.39 | E | O |
| ATOM | 8522 | N | SER | E | 516 | 1.225 | 48.782 | 56.370 | 1.00 | 28.87 | E | N |
| ATOM | 8523 | CA | SER | E | 516 | 2.368 | 49.509 | 56.932 | 1.00 | 32.34 | E | C |
| ATOM | 8524 | CB | SER | E | 516 | 1.890 | 50.632 | 57.861 | 1.00 | 29.10 | E | C |
| ATOM | 8525 | OG | SER | E | 516 | 1.101 | 50.128 | 58.923 | 1.00 | 27.64 | E | O |
| ATOM | 8526 | C | SER | E | 516 | 3.344 | 48.622 | 57.691 | 1.00 | 35.02 | E | C |
| ATOM | 8527 | O | SER | E | 516 | 4.495 | 49.004 | 57.908 | 1.00 | 37.20 | E | O |
| ATOM | 8528 | N | LYS | E | 517 | 2.888 | 47.441 | 58.092 | 1.00 | 38.70 | E | N |
| ATOM | 8529 | CA | LYS | E | 517 | 3.738 | 46.519 | 58.825 | 1.00 | 43.52 | E | C |
| ATOM | 8530 | CB | LYS | E | 517 | 3.008 | 45.207 | 59.084 | 1.00 | 43.96 | E | C |
| ATOM | 8531 | CG | LYS | E | 517 | 2.561 | 45.018 | 60.526 | 1.00 | 44.08 | E | C |
| ATOM | 8532 | CD | LYS | E | 517 | 1.261 | 44.209 | 60.618 | 1.00 | 46.68 | E | C |
| ATOM | 8533 | CE | LYS | E | 517 | 1.071 | 43.234 | 59.436 | 1.00 | 45.64 | E | C |
| ATOM | 8534 | NZ | LYS | E | 517 | 1.653 | 41.888 | 59.709 | 1.00 | 45.03 | E | N |
| ATOM | 8535 | C | LYS | E | 517 | 5.026 | 46.227 | 58.078 | 1.00 | 48.36 | E | C |
| ATOM | 8536 | O | LYS | E | 517 | 5.064 | 46.201 | 56.847 | 1.00 | 49.95 | E | O |
| ATOM | 8537 | N | HIS | E | 518 | 6.077 | 46.012 | 58.859 | 1.00 | 54.31 | E | N |
| ATOM | 8538 | CA | HIS | E | 518 | 7.423 | 45.707 | 58.381 | 1.00 | 57.66 | E | C |
| ATOM | 8539 | CB | HIS | E | 518 | 8.373 | 45.738 | 59.565 | 1.00 | 62.02 | E | C |
| ATOM | 8540 | CG | HIS | E | 518 | 7.918 | 44.868 | 60.696 | 1.00 | 68.52 | E | C |
| ATOM | 8541 | CD2 | HIS | E | 518 | 7.090 | 45.123 | 61.742 | 1.00 | 69.59 | E | C |
| ATOM | 8542 | ND1 | HIS | E | 518 | 8.250 | 43.532 | 60.790 | 1.00 | 70.10 | E | N |
| ATOM | 8543 | CE1 | HIS | E | 518 | 7.647 | 43.002 | 61.841 | 1.00 | 71.42 | E | C |
| ATOM | 8544 | NE2 | HIS | E | 518 | 6.937 | 43.946 | 62.435 | 1.00 | 71.91 | E | N |
| ATOM | 8545 | C | HIS | E | 518 | 7.462 | 44.301 | 57.795 | 1.00 | 58.38 | E | C |
| ATOM | 8546 | O | HIS | E | 518 | 6.625 | 43.457 | 58.123 | 1.00 | 60.46 | E | O |
| ATOM | 8547 | N | SER | E | 519 | 8.446 | 44.046 | 56.942 | 1.00 | 57.70 | E | N |
| ATOM | 8548 | CA | SER | E | 519 | 8.604 | 42.723 | 56.356 | 1.00 | 56.56 | E | C |
| ATOM | 8549 | CB | SER | E | 519 | 8.264 | 42.739 | 54.863 | 1.00 | 54.49 | E | C |
| ATOM | 8550 | OG | SER | E | 519 | 8.458 | 41.452 | 54.301 | 1.00 | 49.64 | E | O |
| ATOM | 8551 | C | SER | E | 519 | 10.054 | 42.294 | 56.554 | 1.00 | 57.47 | E | C |
| ATOM | 8552 | O | SER | E | 519 | 10.345 | 41.369 | 57.318 | 1.00 | 57.91 | E | O |
| ATOM | 8553 | N | GLY | E | 520 | 10.958 | 42.988 | 55.867 | 1.00 | 57.52 | E | N |
| ATOM | 8554 | CA | GLY | E | 520 | 12.372 | 42.682 | 55.970 | 1.00 | 57.23 | E | C |
| ATOM | 8555 | C | GLY | E | 520 | 12.850 | 41.657 | 54.961 | 1.00 | 56.09 | E | C |
| ATOM | 8556 | O | GLY | E | 520 | 14.006 | 41.685 | 54.543 | 1.00 | 58.31 | E | O |
| ATOM | 8557 | N | HIS | E | 521 | 11.961 | 40.756 | 54.560 | 1.00 | 55.41 | E | N |
| ATOM | 8558 | CA | HIS | E | 521 | 12.308 | 39.706 | 53.609 | 1.00 | 57.31 | E | C |
| ATOM | 8559 | CB | HIS | E | 521 | 12.125 | 38.333 | 54.272 | 1.00 | 58.64 | E | C |
| ATOM | 8560 | CG | HIS | E | 521 | 10.921 | 38.244 | 55.167 | 1.00 | 61.89 | E | C |
| ATOM | 8561 | CD2 | HIS | E | 521 | 9.619 | 38.553 | 54.948 | 1.00 | 61.50 | E | C |
| ATOM | 8562 | ND1 | HIS | E | 521 | 10.994 | 37.797 | 56.471 | 1.00 | 63.51 | E | N |
| ATOM | 8563 | CE1 | HIS | E | 521 | 9.790 | 37.835 | 57.015 | 1.00 | 63.25 | E | C |
| ATOM | 8564 | NE2 | HIS | E | 521 | 8.937 | 38.290 | 56.114 | 1.00 | 63.43 | E | N |
| ATOM | 8565 | C | HIS | E | 521 | 11.453 | 39.771 | 52.343 | 1.00 | 55.88 | E | C |
| ATOM | 8566 | O | HIS | E | 521 | 10.284 | 39.384 | 52.367 | 1.00 | 58.49 | E | O |
| ATOM | 8567 | N | MET | E | 522 | 12.016 | 40.246 | 51.235 | 1.00 | 53.08 | E | N |
| ATOM | 8568 | CA | MET | E | 522 | 11.225 | 40.308 | 50.010 | 1.00 | 50.49 | E | C |
| ATOM | 8569 | CB | MET | E | 522 | 11.495 | 41.594 | 49.234 | 1.00 | 53.37 | E | C |
| ATOM | 8570 | CG | MET | E | 522 | 10.237 | 42.123 | 48.550 | 1.00 | 57.01 | E | C |
| ATOM | 8571 | SD | MET | E | 522 | 10.456 | 42.554 | 46.807 | 1.00 | 61.19 | E | S |
| ATOM | 8572 | CE | MET | E | 522 | 11.480 | 44.039 | 46.979 | 1.00 | 59.73 | E | C |
| ATOM | 8573 | C | MET | E | 522 | 11.407 | 39.115 | 49.078 | 1.00 | 47.40 | E | C |
| ATOM | 8574 | O | MET | E | 522 | 12.456 | 38.469 | 49.055 | 1.00 | 46.96 | E | O |
| ATOM | 8575 | N | PHE | E | 523 | 10.353 | 38.842 | 48.317 | 1.00 | 42.43 | E | N |
| ATOM | 8576 | CA | PHE | E | 523 | 10.299 | 37.743 | 47.361 | 1.00 | 38.79 | E | C |
| ATOM | 8577 | CB | PHE | E | 523 | 9.091 | 37.947 | 46.442 | 1.00 | 35.83 | E | C |
| ATOM | 8578 | CG | PHE | E | 523 | 8.619 | 36.693 | 45.772 | 1.00 | 31.69 | E | C |
| ATOM | 8579 | CD1 | PHE | E | 523 | 8.450 | 35.521 | 46.501 | 1.00 | 29.74 | E | C |
| ATOM | 8580 | CD2 | PHE | E | 523 | 8.336 | 36.686 | 44.410 | 1.00 | 30.42 | E | C |
| ATOM | 8581 | CE1 | PHE | E | 523 | 8.007 | 34.358 | 45.881 | 1.00 | 30.43 | E | C |
| ATOM | 8582 | CE2 | PHE | E | 523 | 7.892 | 35.529 | 43.781 | 1.00 | 30.27 | E | C |
| ATOM | 8583 | CZ | PHE | E | 523 | 7.725 | 34.362 | 44.517 | 1.00 | 29.36 | E | C |
| ATOM | 8584 | C | PHE | E | 523 | 11.565 | 37.589 | 46.518 | 1.00 | 37.83 | E | C |
| ATOM | 8585 | O | PHE | E | 523 | 12.065 | 38.557 | 45.948 | 1.00 | 38.07 | E | O |
| ATOM | 8586 | N | SER | E | 524 | 12.068 | 36.361 | 46.429 | 1.00 | 36.03 | E | N |
| ATOM | 8587 | CA | SER | E | 524 | 13.271 | 36.085 | 45.658 | 1.00 | 37.63 | E | C |
| ATOM | 8588 | CB | SER | E | 524 | 14.511 | 36.506 | 46.451 | 1.00 | 34.94 | E | C |
| ATOM | 8589 | OG | SER | E | 524 | 15.300 | 35.382 | 46.796 | 1.00 | 33.33 | E | O |
| ATOM | 8590 | C | SER | E | 524 | 13.379 | 34.605 | 45.299 | 1.00 | 39.03 | E | C |
| ATOM | 8591 | O | SER | E | 524 | 12.531 | 33.797 | 45.679 | 1.00 | 39.29 | E | O |
| ATOM | 8592 | N | SER | E | 525 | 14.431 | 34.263 | 44.563 | 1.00 | 40.88 | E | N |
| ATOM | 8593 | CA | SER | E | 525 | 14.672 | 32.886 | 44.153 | 1.00 | 42.29 | E | C |
| ATOM | 8594 | CB | SER | E | 525 | 15.860 | 32.837 | 43.192 | 1.00 | 43.84 | E | C |
| ATOM | 8595 | OG | SER | E | 525 | 15.510 | 32.171 | 41.993 | 1.00 | 49.76 | E | O |
| ATOM | 8596 | C | SER | E | 525 | 14.970 | 32.009 | 45.367 | 1.00 | 41.38 | E | C |
| ATOM | 8597 | O | SER | E | 525 | 14.685 | 30.811 | 45.370 | 1.00 | 39.76 | E | O |
| ATOM | 8598 | N | LYS | E | 526 | 15.548 | 32.626 | 46.393 | 1.00 | 42.71 | E | N |
| ATOM | 8599 | CA | LYS | E | 526 | 15.921 | 31.938 | 47.625 | 1.00 | 42.74 | E | C |
| ATOM | 8600 | CB | LYS | E | 526 | 16.992 | 32.744 | 48.369 | 1.00 | 47.77 | E | C |
| ATOM | 8601 | CG | LYS | E | 526 | 18.018 | 33.421 | 47.468 | 1.00 | 52.45 | E | C |
| ATOM | 8602 | CD | LYS | E | 526 | 19.421 | 32.866 | 47.712 | 1.00 | 56.22 | E | C |
| ATOM | 8603 | CE | LYS | E | 526 | 20.496 | 33.925 | 47.455 | 1.00 | 59.96 | E | C |
| ATOM | 8604 | NZ | LYS | E | 526 | 21.539 | 33.964 | 48.528 | 1.00 | 59.10 | E | N |
| ATOM | 8605 | C | LYS | E | 526 | 14.744 | 31.688 | 48.568 | 1.00 | 39.76 | E | C |
| ATOM | 8606 | O | LYS | E | 526 | 14.766 | 30.741 | 49.354 | 1.00 | 37.50 | E | O |
| ATOM | 8607 | N | SER | E | 527 | 13.729 | 32.543 | 48.492 | 1.00 | 35.91 | E | N |
| ATOM | 8608 | CA | SER | E | 527 | 12.554 | 32.415 | 49.346 | 1.00 | 33.66 | E | C |
| ATOM | 8609 | CB | SER | E | 527 | 11.473 | 33.400 | 48.896 | 1.00 | 31.72 | E | C |
| ATOM | 8610 | OG | SER | E | 527 | 11.995 | 34.715 | 48.811 | 1.00 | 33.30 | E | O |
| ATOM | 8611 | C | SER | E | 527 | 11.990 | 30.992 | 49.357 | 1.00 | 32.41 | E | C |
| ATOM | 8612 | O | SER | E | 527 | 11.755 | 30.396 | 48.307 | 1.00 | 33.43 | E | O |
| ATOM | 8613 | N | PRO | E | 528 | 11.776 | 30.425 | 50.557 | 1.00 | 31.35 | E | N |
| ATOM | 8614 | CD | PRO | E | 528 | 12.031 | 31.013 | 51.884 | 1.00 | 28.71 | E | C |
| ATOM | 8615 | CA | PRO | E | 528 | 11.235 | 29.066 | 50.660 | 1.00 | 30.18 | E | C |
| ATOM | 8616 | CB | PRO | E | 528 | 11.218 | 28.797 | 52.165 | 1.00 | 28.10 | E | C |
| ATOM | 8617 | CG | PRO | E | 528 | 11.215 | 30.145 | 52.796 | 1.00 | 26.59 | E | C |
| ATOM | 8618 | C | PRO | E | 528 | 9.840 | 28.981 | 50.057 | 1.00 | 31.10 | E | C |
| ATOM | 8619 | O | PRO | E | 528 | 9.109 | 29.973 | 50.041 | 1.00 | 31.86 | E | O |
| ATOM | 8620 | N | LYS | E | 529 | 9.474 | 27.805 | 49.556 | 1.00 | 29.61 | E | N |
| ATOM | 8621 | CA | LYS | E | 529 | 8.153 | 27.626 | 48.973 | 1.00 | 29.85 | E | C |
| ATOM | 8622 | CB | LYS | E | 529 | 8.066 | 26.291 | 48.233 | 1.00 | 31.38 | E | C |
| ATOM | 8623 | CG | LYS | E | 529 | 9.168 | 26.082 | 47.188 | 1.00 | 33.18 | E | C |
| ATOM | 8624 | CD | LYS | E | 529 | 9.114 | 27.126 | 46.083 | 1.00 | 31.96 | E | C |
| ATOM | 8625 | CE | LYS | E | 529 | 10.510 | 27.622 | 45.737 | 1.00 | 34.27 | E | C |
| ATOM | 8626 | NZ | LYS | E | 529 | 10.856 | 27.365 | 44.314 | 1.00 | 30.87 | E | N |
| ATOM | 8627 | C | LYS | E | 529 | 7.153 | 27.662 | 50.122 | 1.00 | 29.62 | E | C |
| ATOM | 8628 | O | LYS | E | 529 | 7.533 | 27.498 | 51.279 | 1.00 | 28.68 | E | O |
| ATOM | 8629 | N | PRO | E | 530 | 5.860 | 27.885 | 49.817 | 1.00 | 30.71 | E | N |
| ATOM | 8630 | CD | PRO | E | 530 | 5.316 | 28.104 | 48.465 | 1.00 | 27.97 | E | C |
| ATOM | 8631 | CA | PRO | E | 530 | 4.802 | 27.948 | 50.837 | 1.00 | 30.51 | E | C |
| ATOM | 8632 | CB | PRO | E | 530 | 3.521 | 27.991 | 50.011 | 1.00 | 29.14 | E | C |
| ATOM | 8633 | CG | PRO | E | 530 | 3.938 | 28.632 | 48.741 | 1.00 | 27.85 | E | C |
| ATOM | 8634 | C | PRO | E | 530 | 4.798 | 26.804 | 51.851 | 1.00 | 31.87 | E | C |
| ATOM | 8635 | O | PRO | E | 530 | 4.629 | 27.030 | 53.055 | 1.00 | 30.52 | E | O |
| ATOM | 8636 | N | GLN | E | 531 | 4.976 | 25.578 | 51.365 | 1.00 | 33.19 | E | N |
| ATOM | 8637 | CA | GLN | E | 531 | 5.001 | 24.405 | 52.236 | 1.00 | 33.50 | E | C |
| ATOM | 8638 | CB | GLN | E | 531 | 4.929 | 23.121 | 51.406 | 1.00 | 33.80 | E | C |
| ATOM | 8639 | CG | GLN | E | 531 | 6.176 | 22.852 | 50.561 | 1.00 | 38.18 | E | C |
| ATOM | 8640 | CD | GLN | E | 531 | 6.071 | 23.423 | 49.154 | 1.00 | 39.43 | E | C |
| ATOM | 8641 | OE1 | GLN | E | 531 | 5.164 | 24.202 | 48.853 | 1.00 | 42.43 | E | O |
| ATOM | 8642 | NE2 | GLN | E | 531 | 7.000 | 23.036 | 48.285 | 1.00 | 38.90 | E | N |
| ATOM | 8643 | C | GLN | E | 531 | 6.263 | 24.385 | 53.097 | 1.00 | 32.69 | E | C |
| ATOM | 8644 | O | GLN | E | 531 | 6.299 | 23.727 | 54.130 | 1.00 | 34.27 | E | O |
| ATOM | 8645 | N | GLU | E | 532 | 7.296 | 25.102 | 52.668 | 1.00 | 31.76 | E | N |
| ATOM | 8646 | CA | GLU | E | 532 | 8.546 | 25.162 | 53.417 | 1.00 | 31.97 | E | C |
| ATOM | 8647 | CB | GLU | E | 532 | 9.734 | 25.289 | 52.460 | 1.00 | 33.67 | E | C |
| ATOM | 8648 | CG | GLU | E | 532 | 10.058 | 24.018 | 51.689 | 1.00 | 39.41 | E | C |
| ATOM | 8649 | CD | GLU | E | 532 | 10.794 | 24.294 | 50.379 | 1.00 | 44.65 | E | C |
| ATOM | 8650 | OE1 | GLU | E | 532 | 11.238 | 25.448 | 50.166 | 1.00 | 45.09 | E | O |
| ATOM | 8651 | OE2 | GLU | E | 532 | 10.926 | 23.353 | 49.560 | 1.00 | 45.81 | E | O |
| ATOM | 8652 | C | GLU | E | 532 | 8.546 | 26.345 | 54.386 | 1.00 | 32.70 | E | C |
| ATOM | 8653 | O | GLU | E | 532 | 9.440 | 26.473 | 55.231 | 1.00 | 34.21 | E | O |
| ATOM | 8654 | N | TRP | E | 533 | 7.547 | 27.215 | 54.256 | 1.00 | 31.62 | E | N |
| ATOM | 8655 | CA | TRP | E | 533 | 7.432 | 28.382 | 55.118 | 1.00 | 26.63 | E | C |
| ATOM | 8656 | CB | TRP | E | 533 | 6.600 | 29.468 | 54.435 | 1.00 | 24.13 | E | C |
| ATOM | 8657 | CG | TRP | E | 533 | 6.676 | 30.785 | 55.137 | 1.00 | 23.35 | E | C |
| ATOM | 8658 | CD2 | TRP | E | 533 | 7.451 | 31.926 | 54.740 | 1.00 | 22.33 | E | C |
| ATOM | 8659 | CE2 | TRP | E | 533 | 7.252 | 32.925 | 55.718 | 1.00 | 21.06 | E | C |
| ATOM | 8660 | CE3 | TRP | E | 533 | 8.292 | 32.200 | 53.652 | 1.00 | 22.44 | E | C |
| ATOM | 8661 | CD1 | TRP | E | 533 | 6.058 | 31.128 | 56.301 | 1.00 | 21.79 | E | C |
| ATOM | 8662 | NE1 | TRP | E | 533 | 6.398 | 32.411 | 56.658 | 1.00 | 22.33 | E | N |
| ATOM | 8663 | CZ2 | TRP | E | 533 | 7.863 | 34.179 | 55.646 | 1.00 | 20.91 | E | C |
| ATOM | 8664 | CZ3 | TRP | E | 533 | 8.906 | 33.451 | 53.578 | 1.00 | 22.20 | E | C |
| ATOM | 8665 | CH2 | TRP | E | 533 | 8.685 | 34.425 | 54.573 | 1.00 | 22.54 | E | C |
| ATOM | 8666 | C | TRP | E | 533 | 6.765 | 27.959 | 56.415 | 1.00 | 26.77 | E | C |
| ATOM | 8667 | O | TRP | E | 533 | 5.562 | 28.141 | 56.601 | 1.00 | 26.63 | E | O |
| ATOM | 8668 | N | THR | E | 534 | 7.553 | 27.392 | 57.318 | 1.00 | 28.37 | E | N |
| ATOM | 8669 | CA | THR | E | 534 | 7.031 | 26.928 | 58.601 | 1.00 | 29.16 | E | C |
| ATOM | 8670 | CB | THR | E | 534 | 7.674 | 25.601 | 58.990 | 1.00 | 28.70 | E | C |
| ATOM | 8671 | OG1 | THR | E | 534 | 9.098 | 25.753 | 58.968 | 1.00 | 34.85 | E | O |
| ATOM | 8672 | CG2 | THR | E | 534 | 7.277 | 24.506 | 58.004 | 1.00 | 28.60 | E | C |
| ATOM | 8673 | C | THR | E | 534 | 7.246 | 27.916 | 59.745 | 1.00 | 29.44 | E | C |
| ATOM | 8674 | O | THR | E | 534 | 6.678 | 27.746 | 60.824 | 1.00 | 29.97 | E | O |
| ATOM | 8675 | N | LEU | E | 535 | 8.055 | 28.949 | 59.516 | 1.00 | 30.31 | E | N |
| ATOM | 8676 | CA | LEU | E | 535 | 8.320 | 29.945 | 60.549 | 1.00 | 30.98 | E | C |
| ATOM | 8677 | CB | LEU | E | 535 | 9.505 | 30.827 | 60.148 | 1.00 | 32.28 | E | C |
| ATOM | 8678 | CG | LEU | E | 535 | 9.529 | 31.396 | 58.726 | 1.00 | 37.89 | E | C |
| ATOM | 8679 | CD1 | LEU | E | 535 | 10.076 | 32.813 | 58.771 | 1.00 | 36.37 | E | C |
| ATOM | 8680 | CD2 | LEU | E | 535 | 10.388 | 30.514 | 57.810 | 1.00 | 39.15 | E | C |
| ATOM | 8681 | C | LEU | E | 535 | 7.083 | 30.800 | 60.827 | 1.00 | 33.04 | E | C |
| ATOM | 8682 | O | LEU | E | 535 | 6.104 | 30.764 | 60.078 | 1.00 | 35.33 | E | O |
| ATOM | 8683 | N | GLU | E | 536 | 7.128 | 31.568 | 61.907 | 1.00 | 33.74 | E | N |
| ATOM | 8684 | CA | GLU | E | 536 | 5.999 | 32.398 | 62.299 | 1.00 | 35.39 | E | C |
| ATOM | 8685 | CB | GLU | E | 536 | 6.084 | 32.698 | 63.796 | 1.00 | 40.43 | E | C |
| ATOM | 8686 | CG | GLU | E | 536 | 4.811 | 32.381 | 64.563 | 1.00 | 46.96 | E | C |
| ATOM | 8687 | CD | GLU | E | 536 | 5.018 | 32.381 | 66.066 | 1.00 | 49.82 | E | C |
| ATOM | 8688 | OE1 | GLU | E | 536 | 4.825 | 33.446 | 66.695 | 1.00 | 51.38 | E | O |
| ATOM | 8689 | OE2 | GLU | E | 536 | 5.374 | 31.315 | 66.614 | 1.00 | 50.52 | E | O |
| ATOM | 8690 | C | GLU | E | 536 | 5.868 | 33.707 | 61.531 | 1.00 | 34.91 | E | C |
| ATOM | 8691 | O | GLU | E | 536 | 4.776 | 34.273 | 61.457 | 1.00 | 35.27 | E | O |
| ATOM | 8692 | N | LYS | E | 537 | 6.976 | 34.185 | 60.971 | 1.00 | 34.12 | E | N |
| ATOM | 8693 | CA | LYS | E | 537 | 6.995 | 35.438 | 60.216 | 1.00 | 34.26 | E | C |
| ATOM | 8694 | CB | LYS | E | 537 | 8.363 | 35.633 | 59.554 | 1.00 | 34.21 | E | C |
| ATOM | 8695 | CG | LYS | E | 537 | 9.311 | 36.532 | 60.322 | 1.00 | 42.86 | E | C |
| ATOM | 8696 | CD | LYS | E | 537 | 8.809 | 37.975 | 60.359 | 1.00 | 48.75 | E | C |
| ATOM | 8697 | CE | LYS | E | 537 | 9.713 | 38.858 | 61.224 | 1.00 | 53.02 | E | C |
| ATOM | 8698 | NZ | LYS | E | 537 | 9.156 | 40.236 | 61.425 | 1.00 | 53.23 | E | N |
| ATOM | 8699 | C | LYS | E | 537 | 5.919 | 35.480 | 59.134 | 1.00 | 32.41 | E | C |
| ATOM | 8700 | O | LYS | E | 537 | 5.659 | 34.478 | 58.465 | 1.00 | 29.76 | E | O |
| ATOM | 8701 | N | ASN | E | 538 | 5.283 | 36.637 | 58.968 | 1.00 | 30.89 | E | N |
| ATOM | 8702 | CA | ASN | E | 538 | 4.273 | 36.772 | 57.924 | 1.00 | 28.20 | E | C |
| ATOM | 8703 | CB | ASN | E | 538 | 3.321 | 37.935 | 58.216 | 1.00 | 27.27 | E | C |
| ATOM | 8704 | CG | ASN | E | 538 | 1.960 | 37.749 | 57.566 | 1.00 | 25.53 | E | C |
| ATOM | 8705 | OD1 | ASN | E | 538 | 1.603 | 36.640 | 57.163 | 1.00 | 26.65 | E | O |
| ATOM | 8706 | ND2 | ASN | E | 538 | 1.190 | 38.833 | 57.461 | 1.00 | 22.44 | E | N |
| ATOM | 8707 | C | ASN | E | 538 | 5.027 | 37.051 | 56.635 | 1.00 | 26.52 | E | C |
| ATOM | 8708 | O | ASN | E | 538 | 5.909 | 37.914 | 56.601 | 1.00 | 28.50 | E | O |
| ATOM | 8709 | N | PRO | E | 539 | 4.711 | 36.313 | 55.561 | 1.00 | 25.94 | E | N |
| ATOM | 8710 | CD | PRO | E | 539 | 3.710 | 35.240 | 55.444 | 1.00 | 25.18 | E | C |
| ATOM | 8711 | CA | PRO | E | 539 | 5.416 | 36.553 | 54.294 | 1.00 | 25.79 | E | C |
| ATOM | 8712 | CB | PRO | E | 539 | 4.799 | 35.533 | 53.331 | 1.00 | 24.02 | E | C |
| ATOM | 8713 | CG | PRO | E | 539 | 4.159 | 34.497 | 54.217 | 1.00 | 23.49 | E | C |
| ATOM | 8714 | C | PRO | E | 539 | 5.191 | 37.990 | 53.824 | 1.00 | 25.63 | E | C |
| ATOM | 8715 | O | PRO | E | 539 | 4.226 | 38.635 | 54.244 | 1.00 | 27.09 | E | O |
| ATOM | 8716 | N | SER | E | 540 | 6.077 | 38.486 | 52.963 | 1.00 | 24.41 | E | N |
| ATOM | 8717 | CA | SER | E | 540 | 5.965 | 39.846 | 52.441 | 1.00 | 20.84 | E | C |
| ATOM | 8718 | CB | SER | E | 540 | 7.211 | 40.201 | 51.612 | 1.00 | 18.39 | E | C |
| ATOM | 8719 | OG | SER | E | 540 | 7.163 | 39.648 | 50.309 | 1.00 | 13.21 | E | O |
| ATOM | 8720 | C | SER | E | 540 | 4.703 | 40.007 | 51.587 | 1.00 | 21.02 | E | C |
| ATOM | 8721 | O | SER | E | 540 | 4.050 | 39.024 | 51.228 | 1.00 | 21.31 | E | O |
| ATOM | 8722 | N | TYR | E | 541 | 4.365 | 41.253 | 51.273 | 1.00 | 20.24 | E | N |
| ATOM | 8723 | CA | TYR | E | 541 | 3.197 | 41.562 | 50.464 | 1.00 | 18.41 | E | C |
| ATOM | 8724 | CB | TYR | E | 541 | 3.096 | 43.083 | 50.275 | 1.00 | 18.80 | E | C |
| ATOM | 8725 | CG | TYR | E | 541 | 1.960 | 43.557 | 49.385 | 1.00 | 18.59 | E | C |
| ATOM | 8726 | CD1 | TYR | E | 541 | 2.118 | 43.630 | 48.002 | 1.00 | 16.78 | E | C |
| ATOM | 8727 | CE1 | TYR | E | 541 | 1.083 | 44.079 | 47.179 | 1.00 | 15.44 | E | C |
| ATOM | 8728 | CD2 | TYR | E | 541 | 0.734 | 43.944 | 49.927 | 1.00 | 14.86 | E | C |
| ATOM | 8729 | CE2 | TYR | E | 541 | −0.312 | 44.397 | 49.110 | 1.00 | 13.12 | E | C |
| ATOM | 8730 | CZ | TYR | E | 541 | −0.127 | 44.461 | 47.736 | 1.00 | 14.82 | E | C |
| ATOM | 8731 | OH | TYR | E | 541 | −1.141 | 44.909 | 46.914 | 1.00 | 10.00 | E | O |
| ATOM | 8732 | C | TYR | E | 541 | 3.304 | 40.869 | 49.108 | 1.00 | 21.82 | E | C |
| ATOM | 8733 | O | TYR | E | 541 | 2.345 | 40.252 | 48.635 | 1.00 | 23.27 | E | O |
| ATOM | 8734 | N | THR | E | 542 | 4.477 | 40.964 | 48.488 | 1.00 | 20.00 | E | N |
| ATOM | 8735 | CA | THR | E | 542 | 4.713 | 40.369 | 47.175 | 1.00 | 20.52 | E | C |
| ATOM | 8736 | CB | THR | E | 542 | 6.085 | 40.816 | 46.638 | 1.00 | 18.26 | E | C |
| ATOM | 8737 | OG1 | THR | E | 542 | 6.091 | 42.243 | 46.530 | 1.00 | 17.38 | E | O |
| ATOM | 8738 | CG2 | THR | E | 542 | 6.361 | 40.215 | 45.272 | 1.00 | 18.79 | E | C |
| ATOM | 8739 | C | THR | E | 542 | 4.614 | 38.844 | 47.163 | 1.00 | 19.85 | E | C |
| ATOM | 8740 | O | THR | E | 542 | 4.210 | 38.248 | 46.164 | 1.00 | 21.22 | E | O |
| ATOM | 8741 | N | TYR | E | 543 | 4.988 | 38.218 | 48.273 | 1.00 | 20.76 | E | N |
| ATOM | 8742 | CA | TYR | E | 543 | 4.911 | 36.767 | 48.402 | 1.00 | 19.88 | E | C |
| ATOM | 8743 | CB | TYR | E | 543 | 5.495 | 36.346 | 49.749 | 1.00 | 21.87 | E | C |
| ATOM | 8744 | CG | TYR | E | 543 | 5.768 | 34.868 | 49.895 | 1.00 | 21.32 | E | C |
| ATOM | 8745 | CD1 | TYR | E | 543 | 4.768 | 33.997 | 50.320 | 1.00 | 23.10 | E | C |
| ATOM | 8746 | CE1 | TYR | E | 543 | 5.024 | 32.635 | 50.515 | 1.00 | 23.96 | E | C |
| ATOM | 8747 | CD2 | TYR | E | 543 | 7.039 | 34.346 | 49.659 | 1.00 | 23.39 | E | C |
| ATOM | 8748 | CE2 | TYR | E | 543 | 7.310 | 32.980 | 49.853 | 1.00 | 23.23 | E | C |
| ATOM | 8749 | CZ | TYR | E | 543 | 6.292 | 32.137 | 50.282 | 1.00 | 23.36 | E | C |
| ATOM | 8750 | OH | TYR | E | 543 | 6.534 | 30.802 | 50.495 | 1.00 | 24.29 | E | O |
| ATOM | 8751 | C | TYR | E | 543 | 3.429 | 36.392 | 48.327 | 1.00 | 19.75 | E | C |
| ATOM | 8752 | O | TYR | E | 543 | 3.028 | 35.485 | 47.597 | 1.00 | 18.77 | E | O |
| ATOM | 8753 | N | TYR | E | 544 | 2.615 | 37.106 | 49.092 | 1.00 | 19.50 | E | N |
| ATOM | 8754 | CA | TYR | E | 544 | 1.176 | 36.872 | 49.100 | 1.00 | 21.04 | E | C |
| ATOM | 8755 | CB | TYR | E | 544 | 0.486 | 37.868 | 50.036 | 1.00 | 20.39 | E | C |
| ATOM | 8756 | CG | TYR | E | 544 | 0.291 | 37.404 | 51.464 | 1.00 | 23.38 | E | C |
| ATOM | 8757 | CD1 | TYR | E | 544 | 1.257 | 37.672 | 52.453 | 1.00 | 25.07 | E | C |
| ATOM | 8758 | CE1 | TYR | E | 544 | 1.034 | 37.338 | 53.793 | 1.00 | 21.69 | E | C |
| ATOM | 8759 | CD2 | TYR | E | 544 | −0.893 | 36.780 | 51.854 | 1.00 | 22.44 | E | C |
| ATOM | 8760 | CE2 | TYR | E | 544 | −1.124 | 36.442 | 53.190 | 1.00 | 24.68 | E | C |
| ATOM | 8761 | CZ | TYR | E | 544 | −0.164 | 36.725 | 54.154 | 1.00 | 25.02 | E | C |
| ATOM | 8762 | OH | TYR | E | 544 | −0.438 | 36.432 | 55.477 | 1.00 | 23.57 | E | O |
| ATOM | 8763 | C | TYR | E | 544 | 0.640 | 37.087 | 47.678 | 1.00 | 22.42 | E | C |
| ATOM | 8764 | O | TYR | E | 544 | −0.004 | 36.213 | 47.092 | 1.00 | 22.10 | E | O |
| ATOM | 8765 | N | ALA | E | 545 | 0.915 | 38.273 | 47.139 | 1.00 | 23.73 | E | N |
| ATOM | 8766 | CA | ALA | E | 545 | 0.472 | 38.661 | 45.807 | 1.00 | 21.60 | E | C |
| ATOM | 8767 | CB | ALA | E | 545 | 1.060 | 40.023 | 45.441 | 1.00 | 21.79 | E | C |
| ATOM | 8768 | C | ALA | E | 545 | 0.824 | 37.642 | 44.738 | 1.00 | 21.30 | E | C |
| ATOM | 8769 | O | ALA | E | 545 | −0.036 | 37.255 | 43.946 | 1.00 | 20.22 | E | O |
| ATOM | 8770 | N | TYR | E | 546 | 2.076 | 37.193 | 44.704 | 1.00 | 19.86 | E | N |
| ATOM | 8771 | CA | TYR | E | 546 | 2.460 | 36.232 | 43.678 | 1.00 | 18.68 | E | C |
| ATOM | 8772 | CB | TYR | E | 546 | 3.941 | 35.863 | 43.766 | 1.00 | 20.73 | E | C |
| ATOM | 8773 | CG | TYR | E | 546 | 4.303 | 34.797 | 42.752 | 1.00 | 24.74 | E | C |
| ATOM | 8774 | CD1 | TYR | E | 546 | 4.577 | 35.135 | 41.425 | 1.00 | 26.58 | E | C |
| ATOM | 8775 | CE1 | TYR | E | 546 | 4.813 | 34.156 | 40.463 | 1.00 | 26.65 | E | C |
| ATOM | 8776 | CD2 | TYR | E | 546 | 4.281 | 33.445 | 43.091 | 1.00 | 26.23 | E | C |
| ATOM | 8777 | CE2 | TYR | E | 546 | 4.516 | 32.458 | 42.134 | 1.00 | 25.91 | E | C |
| ATOM | 8778 | CZ | TYR | E | 546 | 4.776 | 32.824 | 40.822 | 1.00 | 28.27 | E | C |
| ATOM | 8779 | OH | TYR | E | 546 | 4.964 | 31.862 | 39.856 | 1.00 | 28.96 | E | O |
| ATOM | 8780 | C | TYR | E | 546 | 1.654 | 34.948 | 43.721 | 1.00 | 18.77 | E | C |
| ATOM | 8781 | O | TYR | E | 546 | 1.097 | 34.521 | 42.713 | 1.00 | 18.28 | E | O |
| ATOM | 8782 | N | TYR | E | 547 | 1.593 | 34.327 | 44.893 | 1.00 | 20.19 | E | N |
| ATOM | 8783 | CA | TYR | E | 547 | 0.878 | 33.062 | 45.028 | 1.00 | 20.41 | E | C |
| ATOM | 8784 | CB | TYR | E | 547 | 1.242 | 32.403 | 46.355 | 1.00 | 18.16 | E | C |
| ATOM | 8785 | CG | TYR | E | 547 | 2.618 | 31.789 | 46.281 | 1.00 | 18.19 | E | C |
| ATOM | 8786 | CD1 | TYR | E | 547 | 2.836 | 30.631 | 45.538 | 1.00 | 15.17 | E | C |
| ATOM | 8787 | CE1 | TYR | E | 547 | 4.112 | 30.101 | 45.394 | 1.00 | 18.03 | E | C |
| ATOM | 8788 | CD2 | TYR | E | 547 | 3.716 | 32.402 | 46.883 | 1.00 | 14.70 | E | C |
| ATOM | 8789 | CE2 | TYR | E | 547 | 4.996 | 31.876 | 46.742 | 1.00 | 14.85 | E | C |
| ATOM | 8790 | CZ | TYR | E | 547 | 5.184 | 30.728 | 45.996 | 1.00 | 17.14 | E | C |
| ATOM | 8791 | OH | TYR | E | 547 | 6.443 | 30.188 | 45.844 | 1.00 | 22.19 | E | O |
| ATOM | 8792 | C | TYR | E | 547 | −0.626 | 33.150 | 44.848 | 1.00 | 21.50 | E | C |
| ATOM | 8793 | O | TYR | E | 547 | −1.278 | 32.148 | 44.530 | 1.00 | 23.11 | E | O |
| ATOM | 8794 | N | MET | E | 548 | −1.179 | 34.341 | 45.038 | 1.00 | 19.17 | E | N |
| ATOM | 8795 | CA | MET | E | 548 | −2.602 | 34.528 | 44.845 | 1.00 | 16.50 | E | C |
| ATOM | 8796 | CB | MET | E | 548 | −3.076 | 35.778 | 45.583 | 1.00 | 18.09 | E | C |
| ATOM | 8797 | CG | MET | E | 548 | −3.558 | 35.490 | 46.995 | 1.00 | 20.47 | E | C |
| ATOM | 8798 | SD | MET | E | 548 | −4.487 | 36.852 | 47.688 | 1.00 | 25.62 | E | S |
| ATOM | 8799 | CE | MET | E | 548 | −6.138 | 36.499 | 47.062 | 1.00 | 26.29 | E | C |
| ATOM | 8800 | C | MET | E | 548 | −2.817 | 34.671 | 43.341 | 1.00 | 16.93 | E | C |
| ATOM | 8801 | O | MET | E | 548 | −3.778 | 34.150 | 42.784 | 1.00 | 18.11 | E | O |
| ATOM | 8802 | N | TYR | E | 549 | −1.902 | 35.366 | 42.677 | 1.00 | 16.52 | E | N |
| ATOM | 8803 | CA | TYR | E | 549 | −2.002 | 35.555 | 41.239 | 1.00 | 17.68 | E | C |
| ATOM | 8804 | CB | TYR | E | 549 | −0.887 | 36.486 | 40.742 | 1.00 | 18.05 | E | C |
| ATOM | 8805 | CG | TYR | E | 549 | −0.693 | 36.471 | 39.239 | 1.00 | 18.71 | E | C |
| ATOM | 8806 | CD1 | TYR | E | 549 | −1.495 | 37.252 | 38.404 | 1.00 | 17.76 | E | C |
| ATOM | 8807 | CE1 | TYR | E | 549 | −1.334 | 37.229 | 37.014 | 1.00 | 16.16 | E | C |
| ATOM | 8808 | CD2 | TYR | E | 549 | 0.285 | 35.666 | 38.644 | 1.00 | 17.88 | E | C |
| ATOM | 8809 | CE2 | TYR | E | 549 | 0.454 | 35.637 | 37.255 | 1.00 | 14.63 | E | C |
| ATOM | 8810 | CZ | TYR | E | 549 | −0.361 | 36.422 | 36.452 | 1.00 | 16.32 | E | C |
| ATOM | 8811 | OH | TYR | E | 549 | −0.212 | 36.402 | 35.085 | 1.00 | 19.95 | E | O |
| ATOM | 8812 | C | TYR | E | 549 | −1.863 | 34.207 | 40.557 | 1.00 | 18.24 | E | C |
| ATOM | 8813 | O | TYR | E | 549 | −2.653 | 33.851 | 39.690 | 1.00 | 21.22 | E | O |
| ATOM | 8814 | N | ALA | E | 550 | −0.846 | 33.457 | 40.965 | 1.00 | 20.66 | E | N |
| ATOM | 8815 | CA | ALA | E | 550 | −0.557 | 32.150 | 40.391 | 1.00 | 19.47 | E | C |
| ATOM | 8816 | CB | ALA | E | 550 | 0.640 | 31.528 | 41.116 | 1.00 | 16.80 | E | C |
| ATOM | 8817 | C | ALA | E | 550 | −1.751 | 31.198 | 40.421 | 1.00 | 20.16 | E | C |
| ATOM | 8818 | O | ALA | E | 550 | −2.115 | 30.617 | 39.400 | 1.00 | 20.48 | E | O |
| ATOM | 8819 | N | ASN | E | 551 | −2.362 | 31.040 | 41.590 | 1.00 | 20.62 | E | N |
| ATOM | 8820 | CA | ASN | E | 551 | −3.503 | 30.144 | 41.724 | 1.00 | 19.72 | E | C |
| ATOM | 8821 | CB | ASN | E | 551 | −3.845 | 29.955 | 43.204 | 1.00 | 21.12 | E | C |
| ATOM | 8822 | CG | ASN | E | 551 | −2.977 | 28.911 | 43.873 | 1.00 | 20.24 | E | C |
| ATOM | 8823 | OD1 | ASN | E | 551 | −2.032 | 29.242 | 44.592 | 1.00 | 23.45 | E | O |
| ATOM | 8824 | ND2 | ASN | E | 551 | −3.291 | 27.642 | 43.641 | 1.00 | 17.30 | E | N |
| ATOM | 8825 | C | ASN | E | 551 | −4.722 | 30.676 | 40.971 | 1.00 | 20.47 | E | C |
| ATOM | 8826 | O | ASN | E | 551 | −5.486 | 29.905 | 40.389 | 1.00 | 21.66 | E | O |
| ATOM | 8827 | N | ILE | E | 552 | −4.909 | 31.994 | 40.988 | 1.00 | 19.23 | E | N |
| ATOM | 8828 | CA | ILE | E | 552 | −6.034 | 32.614 | 40.298 | 1.00 | 18.03 | E | C |
| ATOM | 8829 | CB | ILE | E | 552 | −6.126 | 34.135 | 40.639 | 1.00 | 18.61 | E | C |
| ATOM | 8830 | CG2 | ILE | E | 552 | −7.067 | 34.860 | 39.657 | 1.00 | 13.47 | E | C |
| ATOM | 8831 | CG1 | ILE | E | 552 | −6.638 | 34.305 | 42.076 | 1.00 | 16.79 | E | C |
| ATOM | 8832 | CD1 | ILE | E | 552 | −6.790 | 35.747 | 42.518 | 1.00 | 13.59 | E | C |
| ATOM | 8833 | C | ILE | E | 552 | −5.889 | 32.428 | 38.785 | 1.00 | 18.58 | E | C |
| ATOM | 8834 | O | ILE | E | 552 | −6.872 | 32.193 | 38.079 | 1.00 | 17.42 | E | O |
| ATOM | 8835 | N | MET | E | 553 | −4.658 | 32.522 | 38.293 | 1.00 | 19.69 | E | N |
| ATOM | 8836 | CA | MET | E | 553 | −4.399 | 32.359 | 36.867 | 1.00 | 22.77 | E | C |
| ATOM | 8837 | CB | MET | E | 553 | −2.928 | 32.601 | 36.558 | 1.00 | 22.26 | E | C |
| ATOM | 8838 | CG | MET | E | 553 | −2.550 | 32.198 | 35.152 | 1.00 | 26.72 | E | C |
| ATOM | 8839 | SD | MET | E | 553 | −0.781 | 31.939 | 34.945 | 1.00 | 34.11 | E | S |
| ATOM | 8840 | CE | MET | E | 553 | −0.791 | 30.320 | 34.227 | 1.00 | 30.77 | E | C |
| ATOM | 8841 | C | MET | E | 553 | −4.782 | 30.963 | 36.394 | 1.00 | 24.14 | E | C |
| ATOM | 8842 | O | MET | E | 553 | −5.495 | 30.808 | 35.397 | 1.00 | 24.79 | E | O |
| ATOM | 8843 | N | VAL | E | 554 | −4.293 | 29.949 | 37.106 | 1.00 | 22.69 | E | N |
| ATOM | 8844 | CA | VAL | E | 554 | −4.584 | 28.563 | 36.770 | 1.00 | 20.53 | E | C |
| ATOM | 8845 | CB | VAL | E | 554 | −3.827 | 27.595 | 37.716 | 1.00 | 21.46 | E | C |
| ATOM | 8846 | CG1 | VAL | E | 554 | −4.073 | 26.148 | 37.297 | 1.00 | 20.59 | E | C |
| ATOM | 8847 | CG2 | VAL | E | 554 | −2.333 | 27.908 | 37.699 | 1.00 | 16.32 | E | C |
| ATOM | 8848 | C | VAL | E | 554 | −6.089 | 28.336 | 36.902 | 1.00 | 21.55 | E | C |
| ATOM | 8849 | O | VAL | E | 554 | −6.731 | 27.787 | 36.009 | 1.00 | 22.93 | E | O |
| ATOM | 8850 | N | LEU | E | 555 | −6.656 | 28.772 | 38.020 | 1.00 | 22.08 | E | N |
| ATOM | 8851 | CA | LEU | E | 555 | −8.090 | 28.615 | 38.245 | 1.00 | 20.69 | E | C |
| ATOM | 8852 | CB | LEU | E | 555 | −8.489 | 29.288 | 39.566 | 1.00 | 17.98 | E | C |
| ATOM | 8853 | CG | LEU | E | 555 | −9.971 | 29.397 | 39.947 | 1.00 | 14.95 | E | C |
| ATOM | 8854 | CD1 | LEU | E | 555 | −10.579 | 28.019 | 40.117 | 1.00 | 14.10 | E | C |
| ATOM | 8855 | CD2 | LEU | E | 555 | −10.093 | 30.187 | 41.238 | 1.00 | 13.64 | E | C |
| ATOM | 8856 | C | LEU | E | 555 | −8.878 | 29.237 | 37.095 | 1.00 | 19.62 | E | C |
| ATOM | 8857 | O | LEU | E | 555 | −9.917 | 28.721 | 36.692 | 1.00 | 18.89 | E | O |
| ATOM | 8858 | N | ASN | E | 556 | −8.375 | 30.347 | 36.566 | 1.00 | 20.11 | E | N |
| ATOM | 8859 | CA | ASN | E | 556 | −9.057 | 31.046 | 35.488 | 1.00 | 20.04 | E | C |
| ATOM | 8860 | CB | ASN | E | 556 | −8.476 | 32.455 | 35.345 | 1.00 | 20.30 | E | C |
| ATOM | 8861 | CG | ASN | E | 556 | −9.170 | 33.475 | 36.254 | 1.00 | 20.87 | E | C |
| ATOM | 8862 | OD1 | ASN | E | 556 | −10.203 | 33.188 | 36.860 | 1.00 | 19.52 | E | O |
| ATOM | 8863 | ND2 | ASN | E | 556 | −8.601 | 34.670 | 36.345 | 1.00 | 21.14 | E | N |
| ATOM | 8864 | C | ASN | E | 556 | −8.995 | 30.294 | 34.157 | 1.00 | 22.30 | E | C |
| ATOM | 8865 | O | ASN | E | 556 | −9.977 | 30.268 | 33.408 | 1.00 | 16.66 | E | O |
| ATOM | 8866 | N | SER | E | 557 | −7.846 | 29.683 | 33.866 | 1.00 | 23.46 | E | N |
| ATOM | 8867 | CA | SER | E | 557 | −7.677 | 28.921 | 32.628 | 1.00 | 23.78 | E | C |
| ATOM | 8868 | CB | SER | E | 557 | −6.253 | 28.366 | 32.519 | 1.00 | 24.13 | E | C |
| ATOM | 8869 | OG | SER | E | 557 | −5.287 | 29.403 | 32.582 | 1.00 | 30.87 | E | O |
| ATOM | 8870 | C | SER | E | 557 | −8.665 | 27.757 | 32.627 | 1.00 | 25.99 | E | C |
| ATOM | 8871 | O | SER | E | 557 | −9.356 | 27.503 | 31.638 | 1.00 | 24.61 | E | O |
| ATOM | 8872 | N | LEU | E | 558 | −8.727 | 27.058 | 33.755 | 1.00 | 26.24 | E | N |
| ATOM | 8873 | CA | LEU | E | 558 | −9.612 | 25.914 | 33.907 | 1.00 | 25.65 | E | C |
| ATOM | 8874 | CB | LEU | E | 558 | −9.372 | 25.259 | 35.269 | 1.00 | 26.55 | E | C |
| ATOM | 8875 | CG | LEU | E | 558 | −10.257 | 24.072 | 35.655 | 1.00 | 27.30 | E | C |
| ATOM | 8876 | CD1 | LEU | E | 558 | −9.961 | 22.891 | 34.752 | 1.00 | 24.79 | E | C |
| ATOM | 8877 | CD2 | LEU | E | 558 | −10.006 | 23.709 | 37.107 | 1.00 | 27.03 | E | C |
| ATOM | 8878 | C | LEU | E | 558 | −11.088 | 26.274 | 33.755 | 1.00 | 24.64 | E | C |
| ATOM | 8879 | O | LEU | E | 558 | −11.816 | 25.618 | 33.017 | 1.00 | 26.95 | E | O |
| ATOM | 8880 | N | ARG | E | 559 | −11.530 | 27.316 | 34.447 | 1.00 | 25.17 | E | N |
| ATOM | 8881 | CA | ARG | E | 559 | −12.927 | 27.735 | 34.384 | 1.00 | 24.55 | E | C |
| ATOM | 8882 | CB | ARG | E | 559 | −13.202 | 28.799 | 35.444 | 1.00 | 22.52 | E | C |
| ATOM | 8883 | CG | ARG | E | 559 | −13.596 | 28.228 | 36.799 | 1.00 | 20.61 | E | C |
| ATOM | 8884 | CD | ARG | E | 559 | −13.820 | 29.336 | 37.817 | 1.00 | 16.36 | E | C |
| ATOM | 8885 | NE | ARG | E | 559 | −15.226 | 29.695 | 37.949 | 1.00 | 10.91 | E | N |
| ATOM | 8886 | CZ | ARG | E | 559 | −16.129 | 28.951 | 38.570 | 1.00 | 11.35 | E | C |
| ATOM | 8887 | NH1 | ARG | E | 559 | −15.775 | 27.795 | 39.118 | 1.00 | 14.34 | E | N |
| ATOM | 8888 | NH2 | ARG | E | 559 | −17.382 | 29.367 | 38.656 | 1.00 | 6.75 | E | N |
| ATOM | 8889 | C | ARG | E | 559 | −13.324 | 28.275 | 33.013 | 1.00 | 26.99 | E | C |
| ATOM | 8890 | O | ARG | E | 559 | −14.486 | 28.185 | 32.607 | 1.00 | 24.85 | E | O |
| ATOM | 8891 | N | LYS | E | 560 | −12.357 | 28.855 | 32.312 | 1.00 | 29.25 | E | N |
| ATOM | 8892 | CA | LYS | E | 560 | −12.605 | 29.401 | 30.986 | 1.00 | 30.42 | E | C |
| ATOM | 8893 | CB | LYS | E | 560 | −11.345 | 30.093 | 30.453 | 1.00 | 31.18 | E | C |
| ATOM | 8894 | CG | LYS | E | 560 | −11.443 | 30.575 | 29.014 | 1.00 | 32.74 | E | C |
| ATOM | 8895 | CD | LYS | E | 560 | −11.919 | 32.024 | 28.937 | 1.00 | 37.72 | E | C |
| ATOM | 8896 | CE | LYS | E | 560 | −11.750 | 32.597 | 27.524 | 1.00 | 40.11 | E | C |
| ATOM | 8897 | NZ | LYS | E | 560 | −12.129 | 34.048 | 27.415 | 1.00 | 37.55 | E | N |
| ATOM | 8898 | C | LYS | E | 560 | −12.972 | 28.235 | 30.086 | 1.00 | 30.88 | E | C |
| ATOM | 8899 | O | LYS | E | 560 | −13.983 | 28.265 | 29.385 | 1.00 | 30.86 | E | O |
| ATOM | 8900 | N | GLU | E | 561 | −12.148 | 27.198 | 30.129 | 1.00 | 30.60 | E | N |
| ATOM | 8901 | CA | GLU | E | 561 | −12.367 | 26.011 | 29.322 | 1.00 | 33.53 | E | C |
| ATOM | 8902 | CB | GLU | E | 561 | −11.224 | 25.020 | 29.536 | 1.00 | 38.82 | F | C |
| ATOM | 8903 | CG | GLU | E | 561 | −10.110 | 25.142 | 28.513 | 1.00 | 48.09 | E | C |
| ATOM | 8904 | CD | GLU | E | 561 | −9.060 | 24.063 | 28.681 | 1.00 | 54.46 | E | C |
| ATOM | 8905 | OE1 | GLU | E | 561 | −9.439 | 22.901 | 28.957 | 1.00 | 56.04 | E | O |
| ATOM | 8906 | OE2 | GLU | E | 561 | −7.855 | 24.375 | 28.541 | 1.00 | 58.51 | E | O |
| ATOM | 8907 | C | GLU | E | 561 | −13.698 | 25.323 | 29.601 | 1.00 | 32.43 | F | C |
| ATOM | 8908 | O | GLU | E | 561 | −14.288 | 24.734 | 28.698 | 1.00 | 33.58 | E | O |
| ATOM | 8909 | N | ARG | E | 562 | −14.172 | 25.387 | 30.844 | 1.00 | 30.78 | E | N |
| ATOM | 8910 | CA | ARG | E | 562 | −15.442 | 24.756 | 31.202 | 1.00 | 25.56 | E | C |
| ATOM | 8911 | CB | ARG | E | 562 | −15.475 | 24.422 | 32.700 | 1.00 | 25.48 | E | C |
| ATOM | 8912 | CG | ARG | E | 562 | −14.293 | 23.581 | 33.189 | 1.00 | 25.70 | E | C |
| ATOM | 8913 | CD | ARG | E | 562 | −14.737 | 22.465 | 34.125 | 1.00 | 24.84 | E | C |
| ATOM | 8914 | NE | ARG | E | 562 | −15.787 | 21.633 | 33.536 | 1.00 | 27.68 | E | N |
| ATOM | 8915 | CZ | ARG | E | 562 | −16.525 | 20.754 | 34.211 | 1.00 | 28.18 | E | C |
| ATOM | 8916 | NH1 | ARG | E | 562 | −16.340 | 20.574 | 35.514 | 1.00 | 29.19 | E | N |
| ATOM | 8917 | NH2 | ARG | E | 562 | −17.453 | 20.051 | 33.579 | 1.00 | 28.49 | E | N |
| ATOM | 8918 | C | ARG | E | 562 | −16.608 | 25.673 | 30.856 | 1.00 | 22.70 | E | C |
| ATOM | 8919 | O | ARG | E | 562 | −17.768 | 25.323 | 31.055 | 1.00 | 22.05 | E | O |
| ATOM | 8920 | N | GLY | E | 563 | −16.297 | 26.850 | 30.329 | 1.00 | 22.76 | E | N |
| ATOM | 8921 | CA | GLY | E | 563 | −17.344 | 27.791 | 29.987 | 1.00 | 22.33 | E | C |
| ATOM | 8922 | C | GLY | E | 563 | −17.899 | 28.441 | 31.242 | 1.00 | 26.00 | E | C |
| ATOM | 8923 | O | GLY | E | 563 | −19.052 | 28.886 | 31.267 | 1.00 | 26.01 | E | O |
| ATOM | 8924 | N | MET | E | 564 | −17.075 | 28.495 | 32.288 | 1.00 | 25.59 | E | N |
| ATOM | 8925 | CA | MET | E | 564 | −17.473 | 29.087 | 33.560 | 1.00 | 22.86 | E | C |
| ATOM | 8926 | CB | MET | E | 564 | −16.996 | 28.213 | 34.722 | 1.00 | 23.00 | E | C |
| ATOM | 8927 | CG | MET | E | 564 | −17.927 | 27.069 | 35.088 | 1.00 | 20.58 | E | C |
| ATOM | 8928 | SD | MET | E | 564 | −17.079 | 25.800 | 36.046 | 1.00 | 19.45 | E | S |
| ATOM | 8929 | CE | MET | E | 564 | −18.418 | 24.915 | 36.715 | 1.00 | 17.05 | E | C |
| ATOM | 8930 | C | MET | E | 564 | −16.861 | 30.473 | 33.690 | 1.00 | 23.14 | E | C |
| ATOM | 8931 | O | MET | E | 564 | −15.918 | 30.808 | 32.975 | 1.00 | 25.00 | E | O |
| ATOM | 8932 | N | ASN | E | 565 | −17.393 | 31.265 | 34.616 | 1.00 | 22.98 | E | N |
| ATOM | 8933 | CA | ASN | E | 565 | −16.912 | 32.627 | 34.856 | 1.00 | 20.55 | E | C |
| ATOM | 8934 | CB | ASN | E | 565 | −17.891 | 33.371 | 35.780 | 1.00 | 20.65 | E | C |
| ATOM | 8935 | CG | ASN | E | 565 | −18.072 | 32.682 | 37.135 | 1.00 | 20.80 | E | C |
| ATOM | 8936 | OD1 | ASN | E | 565 | −18.426 | 31.502 | 37.209 | 1.00 | 18.79 | E | O |
| ATOM | 8937 | ND2 | ASN | E | 565 | −17.828 | 33.424 | 38.210 | 1.00 | 18.41 | E | N |
| ATOM | 8938 | C | ASN | E | 565 | −15.510 | 32.647 | 35.463 | 1.00 | 19.52 | E | C |
| ATOM | 8939 | O | ASN | E | 565 | −15.117 | 31.710 | 36.160 | 1.00 | 20.43 | E | O |
| ATOM | 8940 | N | THR | E | 566 | −14.759 | 33.713 | 35.188 | 1.00 | 16.92 | E | N |
| ATOM | 8941 | CA | THR | E | 566 | −13.403 | 33.865 | 35.712 | 1.00 | 15.07 | E | C |
| ATOM | 8942 | CB | THR | E | 566 | −12.405 | 34.210 | 34.586 | 1.00 | 17.97 | E | C |
| ATOM | 8943 | OG1 | THR | E | 566 | −13.000 | 35.164 | 33.695 | 1.00 | 19.03 | E | O |
| ATOM | 8944 | CG2 | THR | E | 566 | −12.034 | 32.962 | 33.803 | 1.00 | 14.03 | E | C |
| ATOM | 8945 | C | THR | E | 566 | −13.386 | 34.976 | 36.764 | 1.00 | 11.26 | E | C |
| ATOM | 8946 | O | THR | E | 566 | −14.364 | 35.702 | 36.910 | 1.00 | 10.92 | E | O |
| ATOM | 8947 | N | PHE | E | 567 | −12.282 | 35.104 | 37.494 | 1.00 | 11.75 | E | N |
| ATOM | 8948 | CA | PHE | E | 567 | −12.164 | 36.120 | 38.546 | 1.00 | 13.96 | E | C |
| ATOM | 8949 | CB | PHE | E | 567 | −11.976 | 35.464 | 39.923 | 1.00 | 11.62 | E | C |
| ATOM | 8950 | CG | PHE | E | 567 | −12.821 | 34.250 | 40.136 | 1.00 | 9.99 | E | C |
| ATOM | 8951 | CD1 | PHE | E | 567 | −14.168 | 34.374 | 40.441 | 1.00 | 9.19 | E | C |
| ATOM | 8952 | CD2 | PHE | E | 567 | −12.271 | 32.978 | 40.029 | 1.00 | 8.59 | E | C |
| ATOM | 8953 | CE1 | PHE | E | 567 | −14.963 | 33.238 | 40.637 | 1.00 | 10.33 | E | C |
| ATOM | 8954 | CE2 | PHE | E | 567 | −13.057 | 31.843 | 40.221 | 1.00 | 8.57 | E | C |
| ATOM | 8955 | CZ | PHE | E | 567 | −14.400 | 31.974 | 40.525 | 1.00 | 5.39 | E | C |
| ATOM | 8956 | C | PHE | E | 567 | −11.004 | 37.076 | 38.332 | 1.00 | 12.85 | E | C |
| ATOM | 8957 | O | PHE | E | 567 | −9.996 | 36.719 | 37.725 | 1.00 | 16.34 | E | O |
| ATOM | 8958 | N | LEU | E | 568 | −11.147 | 38.291 | 38.852 | 1.00 | 14.68 | E | N |
| ATOM | 8959 | CA | LEU | E | 588 | −10.098 | 39.298 | 38.744 | 1.00 | 13.81 | E | C |
| ATOM | 8960 | CB | LEU | E | 568 | −10.680 | 40.669 | 38.385 | 1.00 | 11.97 | E | C |
| ATOM | 8961 | CG | LEU | E | 568 | −11.656 | 40.826 | 37.219 | 1.00 | 9.91 | E | C |
| ATOM | 8962 | CD1 | LEU | E | 568 | −12.115 | 42.273 | 37.170 | 1.00 | 6.16 | E | C |
| ATOM | 8963 | CD2 | LEU | E | 568 | −10.991 | 40.440 | 35.909 | 1.00 | 7.29 | E | C |
| ATOM | 8964 | C | LEU | E | 568 | −9.416 | 39.403 | 40.098 | 1.00 | 13.07 | E | C |
| ATOM | 8965 | O | LEU | E | 568 | −9.991 | 39.019 | 41.116 | 1.00 | 8.76 | E | O |
| ATOM | 8966 | N | PHE | E | 569 | −8.189 | 39.919 | 40.092 | 1.00 | 14.72 | E | N |
| ATOM | 8967 | CA | PHE | E | 569 | −7.406 | 40.117 | 41.306 | 1.00 | 13.41 | E | C |
| ATOM | 8968 | CB | PHE | E | 569 | −6.016 | 39.484 | 41.127 | 1.00 | 14.00 | E | C |
| ATOM | 8969 | CG | PHE | E | 569 | −5.126 | 39.557 | 42.350 | 1.00 | 11.67 | E | C |
| ATOM | 8970 | CD1 | PHE | E | 569 | −5.620 | 39.271 | 43.617 | 1.00 | 11.41 | E | C |
| ATOM | 8971 | CD2 | PHE | E | 569 | −3.788 | 39.914 | 42.223 | 1.00 | 9.47 | E | C |
| ATOM | 8972 | CE1 | PHE | E | 569 | −4.789 | 39.341 | 44.744 | 1.00 | 12.15 | E | C |
| ATOM | 8973 | CE2 | PHE | E | 569 | −2.950 | 39.987 | 43.339 | 1.00 | 13.45 | E | C |
| ATOM | 8974 | CZ | PHE | E | 569 | −3.454 | 39.700 | 44.602 | 1.00 | 11.13 | E | C |
| ATOM | 8975 | C | PHE | E | 569 | −7.312 | 41.635 | 41.505 | 1.00 | 13.88 | E | C |
| ATOM | 8976 | O | PHE | E | 569 | −6.636 | 42.322 | 40.746 | 1.00 | 14.12 | E | O |
| ATOM | 8977 | N | ARG | E | 570 | −8.014 | 42.144 | 42.516 | 1.00 | 15.88 | E | N |
| ATOM | 8978 | CA | ARG | E | 570 | −8.042 | 43.571 | 42.834 | 1.00 | 15.97 | E | C |
| ATOM | 8979 | CB | ARG | E | 570 | −9.448 | 44.120 | 42.581 | 1.00 | 15.23 | E | C |
| ATOM | 8980 | CG | ARG | E | 570 | −10.068 | 43.646 | 41.267 | 1.00 | 11.85 | E | C |
| ATOM | 8981 | CD | ARG | E | 570 | −11.582 | 43.858 | 41.223 | 1.00 | 9.53 | E | C |
| ATOM | 8982 | NE | ARG | E | 570 | −11.993 | 45.204 | 41.618 | 1.00 | 7.13 | E | N |
| ATOM | 8983 | CZ | ARG | E | 570 | −13.256 | 45.617 | 41.637 | 1.00 | 6.80 | E | C |
| ATOM | 8984 | NH1 | ARG | E | 570 | −14.227 | 44.791 | 41.281 | 1.00 | 7.98 | E | N |
| ATOM | 8985 | NH2 | ARG | E | 570 | −13.557 | 46.846 | 42.030 | 1.00 | 5.18 | E | N |
| ATOM | 8986 | C | ARG | E | 570 | −7.665 | 43.780 | 44.305 | 1.00 | 15.67 | E | C |
| ATOM | 8987 | O | ARG | E | 570 | −8.529 | 44.010 | 45.150 | 1.00 | 17.11 | E | O |
| ATOM | 8988 | N | PRO | E | 571 | −6.364 | 43.744 | 44.624 | 1.00 | 13.10 | E | N |
| ATOM | 8989 | CD | PRO | E | 571 | −5.216 | 43.562 | 43.721 | 1.00 | 10.42 | E | C |
| ATOM | 8990 | CA | PRO | E | 571 | −5.929 | 43.922 | 46.013 | 1.00 | 12.82 | E | C |
| ATOM | 8991 | CB | PRO | E | 571 | −4.561 | 43.256 | 46.029 | 1.00 | 10.64 | E | C |
| ATOM | 8992 | CG | PRO | E | 571 | −4.023 | 43.572 | 44.664 | 1.00 | 10.26 | E | C |
| ATOM | 8993 | C | PRO | E | 571 | −5.833 | 45.359 | 46.515 | 1.00 | 14.63 | E | C |
| ATOM | 8994 | O | PRO | E | 571 | −5.889 | 46.315 | 45.737 | 1.00 | 13.59 | E | O |
| ATOM | 8995 | N | HIS | E | 572 | −5.701 | 45.490 | 47.833 | 1.00 | 13.06 | E | N |
| ATOM | 8996 | CA | HIS | E | 572 | −5.522 | 46.787 | 48.459 | 1.00 | 12.99 | E | C |
| ATOM | 8997 | CB | HIS | E | 572 | −5.714 | 46.697 | 49.976 | 1.00 | 13.98 | E | C |
| ATOM | 8998 | CG | HIS | E | 572 | −7.131 | 46.864 | 50.425 | 1.00 | 11.11 | E | C |
| ATOM | 8999 | CD2 | HIS | E | 572 | −7.668 | 47.608 | 51.420 | 1.00 | 12.20 | E | C |
| ATOM | 9000 | ND1 | HIS | E | 572 | −8.183 | 46.194 | 49.839 | 1.00 | 11.21 | E | N |
| ATOM | 9001 | CE1 | HIS | E | 572 | −9.307 | 46.518 | 50.453 | 1.00 | 13.55 | E | C |
| ATOM | 9002 | NE2 | HIS | E | 572 | −9.019 | 47.376 | 51.420 | 1.00 | 13.51 | E | N |
| ATOM | 9003 | C | HIS | E | 572 | −4.054 | 47.007 | 48.157 | 1.00 | 12.50 | E | C |
| ATOM | 9004 | O | HIS | E | 572 | −3.260 | 46.076 | 48.294 | 1.00 | 12.88 | E | O |
| ATOM | 9005 | N | CYS | E | 573 | −3.679 | 48.210 | 47.735 | 1.00 | 11.11 | E | N |
| ATOM | 9006 | CA | CYS | E | 573 | −2.282 | 48.452 | 47.420 | 1.00 | 10.46 | E | C |
| ATOM | 9007 | CB | CYS | E | 573 | −1.972 | 47.912 | 46.026 | 1.00 | 11.72 | E | C |
| ATOM | 9008 | SG | CYS | E | 573 | −0.210 | 47.900 | 45.569 | 1.00 | 18.82 | E | S |
| ATOM | 9009 | C | CYS | E | 573 | −1.927 | 49.918 | 47.496 | 1.00 | 10.58 | E | C |
| ATOM | 9010 | O | CYS | E | 573 | −2.706 | 50.774 | 47.089 | 1.00 | 11.81 | E | O |
| ATOM | 9011 | N | GLY | E | 574 | −0.751 | 50.197 | 48.045 | 1.00 | 12.39 | E | N |
| ATOM | 9012 | CA | GLY | E | 574 | −0.280 | 51.564 | 48.159 | 1.00 | 13.21 | E | C |
| ATOM | 9013 | C | GLY | E | 574 | −0.875 | 52.433 | 49.250 | 1.00 | 15.25 | E | C |
| ATOM | 9014 | O | GLY | E | 574 | −0.643 | 53.642 | 49.260 | 1.00 | 15.58 | E | O |
| ATOM | 9015 | N | GLU | E | 575 | −1.656 | 51.855 | 50.155 | 1.00 | 16.10 | E | N |
| ATOM | 9016 | CA | GLU | E | 575 | −2.225 | 52.654 | 51.236 | 1.00 | 15.90 | E | C |
| ATOM | 9017 | CB | GLU | E | 575 | −3.208 | 51.836 | 52.073 | 1.00 | 14.19 | E | C |
| ATOM | 9018 | CG | GLU | E | 575 | −3.909 | 52.647 | 53.144 | 1.00 | 12.26 | E | C |
| ATOM | 9019 | CD | GLU | E | 575 | −4.921 | 51.832 | 53.912 | 1.00 | 16.47 | E | C |
| ATOM | 9020 | OE1 | GLU | E | 575 | −5.907 | 52.404 | 54.421 | 1.00 | 17.82 | E | O |
| ATOM | 9021 | OE2 | GLU | E | 575 | −4.730 | 50.605 | 54.007 | 1.00 | 18.69 | E | O |
| ATOM | 9022 | C | GLU | E | 575 | −1.059 | 53.084 | 52.107 | 1.00 | 16.40 | E | C |
| ATOM | 9023 | O | GLU | E | 575 | −1.076 | 54.155 | 52.709 | 1.00 | 18.12 | E | O |
| ATOM | 9024 | N | VAL | E | 576 | −0.055 | 52.216 | 52.169 | 1.00 | 17.11 | E | N |
| ATOM | 9025 | CA | VAL | E | 576 | 1.168 | 52.450 | 52.927 | 1.00 | 19.54 | E | C |
| ATOM | 9026 | CB | VAL | E | 576 | 0.913 | 52.562 | 54.434 | 1.00 | 22.43 | E | C |
| ATOM | 9027 | CG1 | VAL | E | 576 | 0.673 | 54.028 | 54.812 | 1.00 | 31.09 | E | C |
| ATOM | 9028 | CG2 | VAL | E | 576 | −0.261 | 51.695 | 54.830 | 1.00 | 27.98 | E | C |
| ATOM | 9029 | C | VAL | E | 576 | 2.120 | 51.294 | 52.696 | 1.00 | 17.23 | E | C |
| ATOM | 9030 | O | VAL | E | 576 | 1.796 | 50.347 | 51.995 | 1.00 | 19.04 | E | O |
| ATOM | 9031 | N | GLY | E | 577 | 3.298 | 51.374 | 53.290 | 1.00 | 18.25 | E | N |
| ATOM | 9032 | CA | GLY | E | 577 | 4.272 | 50.316 | 53.119 | 1.00 | 18.54 | E | C |
| ATOM | 9033 | C | GLY | E | 577 | 5.275 | 50.707 | 52.058 | 1.00 | 19.48 | E | C |
| ATOM | 9034 | O | GLY | E | 577 | 5.377 | 51.878 | 51.698 | 1.00 | 20.68 | E | O |
| ATOM | 9035 | N | ALA | E | 578 | 6.009 | 49.727 | 51.548 | 1.00 | 18.91 | E | N |
| ATOM | 9036 | CA | ALA | E | 578 | 7.012 | 49.971 | 50.525 | 1.00 | 20.61 | E | C |
| ATOM | 9037 | CB | ALA | E | 578 | 7.986 | 48.803 | 50.484 | 1.00 | 18.11 | E | C |
| ATOM | 9038 | C | ALA | E | 578 | 6.392 | 50.182 | 49.142 | 1.00 | 22.48 | E | C |
| ATOM | 9039 | O | ALA | E | 578 | 5.292 | 49.708 | 48.866 | 1.00 | 22.76 | E | O |
| ATOM | 9040 | N | LEU | E | 579 | 7.110 | 50.888 | 48.273 | 1.00 | 24.97 | E | N |
| ATOM | 9041 | CA | LEU | E | 579 | 6.642 | 51.151 | 46.915 | 1.00 | 23.80 | E | C |
| ATOM | 9042 | CB | LEU | E | 579 | 7.615 | 52.078 | 46.182 | 1.00 | 24.07 | E | C |
| ATOM | 9043 | CG | LEU | E | 579 | 7.421 | 53.580 | 46.368 | 1.00 | 23.38 | E | C |
| ATOM | 9044 | CD1 | LEU | E | 579 | 8.667 | 54.307 | 45.897 | 1.00 | 23.60 | E | C |
| ATOM | 9045 | CD2 | LEU | E | 579 | 6.198 | 54.044 | 45.596 | 1.00 | 26.51 | E | C |
| ATOM | 9046 | C | LEU | E | 579 | 6.525 | 49.848 | 46.136 | 1.00 | 25.16 | E | C |
| ATOM | 9047 | O | LEU | E | 579 | 5.665 | 49.713 | 45.262 | 1.00 | 27.36 | E | O |
| ATOM | 9048 | N | THR | E | 580 | 7.391 | 48.891 | 46.458 | 1.00 | 23.05 | E | N |
| ATOM | 9049 | CA | THR | E | 580 | 7.386 | 47.603 | 45.777 | 1.00 | 23.79 | E | C |
| ATOM | 9050 | CB | THR | E | 580 | 8.369 | 46.602 | 46.441 | 1.00 | 25.10 | E | C |
| ATOM | 9051 | OG1 | THR | E | 580 | 7.823 | 46.132 | 47.678 | 1.00 | 31.08 | E | O |
| ATOM | 9052 | CG2 | THR | E | 580 | 9.704 | 47.262 | 46.703 | 1.00 | 23.46 | E | C |
| ATOM | 9053 | C | THR | E | 580 | 6.006 | 46.955 | 45.718 | 1.00 | 19.87 | E | C |
| ATOM | 9054 | O | THR | E | 580 | 5.797 | 46.023 | 44.950 | 1.00 | 23.19 | E | O |
| ATOM | 9055 | N | HIS | E | 581 | 5.070 | 47.441 | 46.525 | 1.00 | 18.02 | E | N |
| ATOM | 9056 | CA | HIS | E | 581 | 3.716 | 46.897 | 46.536 | 1.00 | 16.96 | E | C |
| ATOM | 9057 | CB | HIS | E | 581 | 2.916 | 47.420 | 47.738 | 1.00 | 17.66 | E | C |
| ATOM | 9058 | CG | HIS | E | 581 | 3.444 | 46.979 | 49.066 | 1.00 | 17.63 | E | C |
| ATOM | 9059 | CD2 | HIS | E | 581 | 4.620 | 46.406 | 49.414 | 1.00 | 17.27 | E | C |
| ATOM | 9060 | ND1 | HIS | E | 581 | 2.729 | 47.129 | 50.235 | 1.00 | 16.22 | E | N |
| ATOM | 9061 | CE1 | HIS | E | 581 | 3.442 | 46.669 | 51.246 | 1.00 | 12.13 | E | C |
| ATOM | 9062 | NE2 | HIS | E | 581 | 4.593 | 46.225 | 50.775 | 1.00 | 15.31 | E | N |
| ATOM | 9063 | C | HIS | E | 581 | 2.976 | 47.301 | 45.268 | 1.00 | 16.86 | E | C |
| ATOM | 9064 | O | HIS | E | 581 | 2.205 | 46.521 | 44.716 | 1.00 | 16.77 | E | O |
| ATOM | 9065 | N | LEU | E | 582 | 3.202 | 48.533 | 44.822 | 1.00 | 15.90 | E | N |
| ATOM | 9066 | CA | LEU | E | 582 | 2.539 | 49.046 | 43.628 | 1.00 | 16.10 | E | C |
| ATOM | 9067 | CB | LEU | E | 582 | 2.647 | 50.574 | 43.588 | 1.00 | 13.20 | E | C |
| ATOM | 9068 | CG | LEU | E | 582 | 1.789 | 51.235 | 44.665 | 1.00 | 9.75 | E | C |
| ATOM | 9069 | CD1 | LEU | E | 582 | 2.399 | 52.540 | 45.069 | 1.00 | 8.18 | E | C |
| ATOM | 9070 | CD2 | LEU | E | 582 | 0.370 | 51.420 | 44.147 | 1.00 | 10.02 | E | C |
| ATOM | 9071 | C | LEU | E | 582 | 3.151 | 48.434 | 42.381 | 1.00 | 16.09 | E | C |
| ATOM | 9072 | O | LEU | E | 582 | 2.474 | 48.223 | 41.374 | 1.00 | 15.45 | E | O |
| ATOM | 9073 | N | MET | E | 583 | 4.440 | 48.140 | 42.466 | 1.00 | 16.76 | E | N |
| ATOM | 9074 | CA | MET | E | 583 | 5.157 | 47.540 | 41.363 | 1.00 | 16.62 | E | C |
| ATOM | 9075 | CB | MET | E | 583 | 6.647 | 47.500 | 41.691 | 1.00 | 19.81 | E | C |
| ATOM | 9076 | CG | MET | E | 583 | 7.501 | 46.825 | 40.646 | 1.00 | 27.47 | E | C |
| ATOM | 9077 | SD | MET | E | 583 | 8.366 | 45.384 | 41.303 | 1.00 | 36.62 | E | S |
| ATOM | 9078 | CE | MET | E | 583 | 7.221 | 44.090 | 40.867 | 1.00 | 30.56 | E | C |
| ATOM | 9079 | C | MET | E | 583 | 4.618 | 46.133 | 41.124 | 1.00 | 16.99 | E | C |
| ATOM | 9080 | O | MET | E | 583 | 4.343 | 45.748 | 39.993 | 1.00 | 20.41 | E | O |
| ATOM | 9081 | N | THR | E | 584 | 4.448 | 45.373 | 42.199 | 1.00 | 17.33 | E | N |
| ATOM | 9082 | CA | THR | E | 584 | 3.950 | 43.999 | 42.109 | 1.00 | 15.07 | E | C |
| ATOM | 9083 | CB | THR | E | 584 | 4.074 | 43.292 | 43.492 | 1.00 | 15.78 | E | C |
| ATOM | 9084 | OG1 | THR | E | 584 | 5.441 | 42.928 | 43.719 | 1.00 | 9.62 | E | O |
| ATOM | 9085 | CG2 | THR | E | 584 | 3.226 | 42.036 | 43.546 | 1.00 | 14.38 | E | C |
| ATOM | 9086 | C | THR | E | 584 | 2.496 | 43.959 | 41.617 | 1.00 | 14.26 | E | C |
| ATOM | 9087 | O | THR | E | 584 | 2.068 | 43.004 | 40.956 | 1.00 | 10.61 | E | O |
| ATOM | 9088 | N | ALA | E | 585 | 1.737 | 44.999 | 41.944 | 1.00 | 14.24 | E | N |
| ATOM | 9089 | CA | ALA | E | 585 | 0.346 | 45.078 | 41.517 | 1.00 | 14.75 | E | C |
| ATOM | 9090 | CB | ALA | E | 585 | −0.410 | 46.110 | 42.352 | 1.00 | 12.05 | E | C |
| ATOM | 9091 | C | ALA | E | 585 | 0.309 | 45.465 | 40.040 | 1.00 | 15.54 | E | C |
| ATOM | 9092 | O | ALA | E | 585 | −0.630 | 45.120 | 39.330 | 1.00 | 16.28 | E | O |
| ATOM | 9093 | N | PHE | E | 586 | 1.327 | 46.186 | 39.580 | 1.00 | 15.15 | E | N |
| ATOM | 9094 | CA | PHE | E | 586 | 1.386 | 46.582 | 38.178 | 1.00 | 16.34 | E | C |
| ATOM | 9095 | CB | PHE | E | 586 | 2.602 | 47.490 | 37.929 | 1.00 | 13.43 | E | C |
| ATOM | 9096 | CG | PHE | E | 586 | 2.863 | 47.783 | 36.471 | 1.00 | 11.73 | E | C |
| ATOM | 9097 | CD1 | PHE | E | 586 | 2.145 | 48.769 | 35.802 | 1.00 | 12.06 | E | C |
| ATOM | 9098 | CD2 | PHE | E | 586 | 3.820 | 47.059 | 35.763 | 1.00 | 12.21 | E | C |
| ATOM | 9099 | CE1 | PHE | E | 586 | 2.375 | 49.025 | 34.452 | 1.00 | 11.29 | E | C |
| ATOM | 9100 | CE2 | PHE | E | 586 | 4.058 | 47.307 | 34.408 | 1.00 | 10.45 | E | C |
| ATOM | 9101 | CZ | PHE | E | 586 | 3.339 | 48.286 | 33.752 | 1.00 | 11.23 | E | C |
| ATOM | 9102 | C | PHE | E | 586 | 1.492 | 45.310 | 37.335 | 1.00 | 17.32 | E | C |
| ATOM | 9103 | O | PHE | E | 586 | 1.018 | 45.261 | 36.201 | 1.00 | 18.89 | E | O |
| ATOM | 9104 | N | MET | E | 587 | 2.103 | 44.278 | 37.913 | 1.00 | 17.15 | E | N |
| ATOM | 9105 | CA | MET | E | 587 | 2.297 | 42.992 | 37.242 | 1.00 | 19.42 | E | C |
| ATOM | 9106 | CB | MET | E | 587 | 3.551 | 42.277 | 37.784 | 1.00 | 18.59 | E | C |
| ATOM | 9107 | CG | MET | E | 587 | 4.875 | 43.005 | 37.654 | 1.00 | 21.38 | E | C |
| ATOM | 9108 | SD | MET | E | 587 | 6.238 | 41.991 | 38.317 | 1.00 | 24.15 | E | S |
| ATOM | 9109 | CE | MET | E | 587 | 6.079 | 40.483 | 37.331 | 1.00 | 22.70 | E | C |
| ATOM | 9110 | C | MET | E | 587 | 1.142 | 41.995 | 37.402 | 1.00 | 18.84 | E | C |
| ATOM | 9111 | O | MET | E | 587 | 0.874 | 41.207 | 36.498 | 1.00 | 17.83 | E | O |
| ATOM | 9112 | N | THR | E | 588 | 0.464 | 42.036 | 38.547 | 1.00 | 17.36 | E | N |
| ATOM | 9113 | CA | THR | E | 588 | −0.574 | 41.051 | 38.854 | 1.00 | 14.53 | E | C |
| ATOM | 9114 | CB | THR | E | 588 | −0.211 | 40.312 | 40.161 | 1.00 | 15.42 | E | C |
| ATOM | 9115 | OG1 | THR | E | 588 | −0.090 | 41.274 | 41.221 | 1.00 | 14.75 | E | O |
| ATOM | 9116 | CG2 | THR | E | 588 | 1.127 | 39.576 | 40.026 | 1.00 | 14.30 | E | C |
| ATOM | 9117 | C | THR | E | 588 | −2.039 | 41.440 | 39.007 | 1.00 | 14.53 | E | C |
| ATOM | 9118 | O | THR | E | 588 | −2.916 | 40.560 | 38.955 | 1.00 | 14.04 | E | O |
| ATOM | 9119 | N | ALA | E | 589 | −2.337 | 42.719 | 39.188 | 1.00 | 10.85 | E | N |
| ATOM | 9120 | CA | ALA | E | 589 | −3.728 | 43.087 | 39.414 | 1.00 | 12.34 | E | C |
| ATOM | 9121 | CB | ALA | E | 589 | −3.822 | 43.880 | 40.705 | 1.00 | 9.60 | E | C |
| ATOM | 9122 | C | ALA | E | 589 | −4.467 | 43.828 | 38.308 | 1.00 | 14.05 | E | C |
| ATOM | 9123 | O | ALA | E | 589 | −3.900 | 44.693 | 37.637 | 1.00 | 14.14 | E | O |
| ATOM | 9124 | N | ASP | E | 590 | −5.746 | 43.492 | 38.140 | 1.00 | 11.94 | E | N |
| ATOM | 9125 | CA | ASP | E | 590 | −6.584 | 44.139 | 37.146 | 1.00 | 15.29 | E | C |
| ATOM | 9126 | CB | ASP | E | 590 | −7.960 | 43.477 | 37.114 | 1.00 | 16.21 | E | C |
| ATOM | 9127 | CG | ASP | E | 590 | −8.862 | 44.049 | 36.031 | 1.00 | 18.61 | E | C |
| ATOM | 9128 | OD1 | ASP | E | 590 | −9.491 | 45.100 | 36.284 | 1.00 | 18.02 | E | O |
| ATOM | 9129 | OD2 | ASP | E | 590 | −8.946 | 43.452 | 34.930 | 1.00 | 17.58 | E | O |
| ATOM | 9130 | C | ASP | E | 590 | −6.695 | 45.610 | 37.557 | 1.00 | 18.27 | E | C |
| ATOM | 9131 | O | ASP | E | 590 | −6.520 | 46.513 | 36.741 | 1.00 | 19.09 | E | O |
| ATOM | 9132 | N | ASN | E | 591 | −6.984 | 45.835 | 38.836 | 1.00 | 19.33 | E | N |
| ATOM | 9133 | CA | ASN | E | 591 | −7.079 | 47.179 | 39.406 | 1.00 | 14.74 | E | C |
| ATOM | 9134 | CB | ASN | E | 591 | −8.441 | 47.826 | 39.086 | 1.00 | 13.64 | E | C |
| ATOM | 9135 | CG | ASN | E | 591 | −9.607 | 47.119 | 39.738 | 1.00 | 10.72 | E | C |
| ATOM | 9136 | OD1 | ASN | E | 591 | −10.300 | 46.322 | 39.113 | 1.00 | 13.92 | E | O |
| ATOM | 9137 | ND2 | ASN | E | 591 | −9.840 | 47.422 | 40.995 | 1.00 | 14.56 | E | N |
| ATOM | 9138 | C | ASN | E | 591 | −6.829 | 47.080 | 40.921 | 1.00 | 15.67 | E | C |
| ATOM | 9139 | O | ASN | E | 591 | −6.786 | 45.983 | 41.469 | 1.00 | 12.96 | E | O |
| ATOM | 9140 | N | ILE | E | 592 | −6.647 | 48.222 | 41.586 | 1.00 | 17.74 | E | N |
| ATOM | 9141 | CA | ILE | E | 592 | −6.361 | 48.256 | 43.022 | 1.00 | 14.73 | E | C |
| ATOM | 9142 | CB | ILE | E | 592 | −4.897 | 48.703 | 43.294 | 1.00 | 14.03 | E | C |
| ATOM | 9143 | CG2 | ILE | E | 592 | −3.909 | 47.784 | 42.592 | 1.00 | 13.03 | E | C |
| ATOM | 9144 | CG1 | ILE | E | 592 | −4.708 | 50.144 | 42.808 | 1.00 | 10.55 | E | C |
| ATOM | 9145 | CD1 | ILE | E | 592 | −3.408 | 50.787 | 43.262 | 1.00 | 7.83 | E | C |
| ATOM | 9146 | C | ILE | E | 592 | −7.246 | 49.224 | 43.798 | 1.00 | 14.69 | E | C |
| ATOM | 9147 | O | ILE | E | 592 | −8.086 | 49.930 | 43.224 | 1.00 | 10.02 | E | O |
| ATOM | 9148 | N | SER | E | 593 | −7.027 | 49.241 | 45.115 | 1.00 | 13.22 | E | N |
| ATOM | 9149 | CA | SER | E | 593 | −7.725 | 50.136 | 46.035 | 1.00 | 11.94 | E | C |
| ATOM | 9150 | CB | SER | E | 593 | −8.490 | 49.354 | 47.088 | 1.00 | 11.04 | E | C |
| ATOM | 9151 | OG | SER | E | 593 | −9.555 | 48.638 | 46.511 | 1.00 | 16.02 | E | O |
| ATOM | 9152 | C | SER | E | 593 | −6.652 | 50.966 | 46.728 | 1.00 | 12.53 | E | C |
| ATOM | 9153 | O | SER | E | 593 | −5.569 | 50.445 | 47.033 | 1.00 | 12.21 | E | O |
| ATOM | 9154 | N | HIS | E | 594 | −6.961 | 52.245 | 46.962 | 1.00 | 11.27 | E | N |
| ATOM | 9155 | CA | HIS | E | 594 | −6.063 | 53.214 | 47.621 | 1.00 | 10.80 | E | C |
| ATOM | 9156 | CB | HIS | E | 594 | −5.344 | 52.577 | 48.827 | 1.00 | 10.60 | E | C |
| ATOM | 9157 | CG | HIS | E | 594 | −6.258 | 52.241 | 49.965 | 1.00 | 10.41 | E | C |
| ATOM | 9158 | CD2 | HIS | E | 594 | −6.480 | 51.075 | 50.619 | 1.00 | 8.53 | E | C |
| ATOM | 9159 | ND1 | HIS | E | 594 | −7.135 | 53.156 | 50.511 | 1.00 | 12.17 | E | N |
| ATOM | 9160 | CE1 | HIS | E | 594 | −7.860 | 52.567 | 51.448 | 1.00 | 7.88 | E | C |
| ATOM | 9161 | NE2 | HIS | E | 594 | −7.481 | 51.304 | 51.532 | 1.00 | 8.88 | E | N |
| ATOM | 9162 | C | HIS | E | 594 | −5.045 | 53.821 | 46.661 | 1.00 | 9.68 | E | C |
| ATOM | 9163 | O | HIS | E | 594 | −5.282 | 54.885 | 46.101 | 1.00 | 13.48 | E | O |
| ATOM | 9164 | N | GLY | E | 595 | −3.913 | 53.159 | 46.472 | 1.00 | 9.59 | E | N |
| ATOM | 9165 | CA | GLY | E | 595 | −2.906 | 53.672 | 45.558 | 1.00 | 11.40 | E | C |
| ATOM | 9166 | C | GLY | E | 595 | −2.250 | 54.997 | 45.907 | 1.00 | 12.32 | E | C |
| ATOM | 9167 | O | GLY | E | 595 | −1.645 | 55.632 | 45.051 | 1.00 | 13.93 | E | O |
| ATOM | 9168 | N | LEU | E | 596 | −2.329 | 55.407 | 47.167 | 1.00 | 15.20 | E | N |
| ATOM | 9169 | CA | LEU | E | 596 | −1.749 | 56.680 | 47.607 | 1.00 | 14.08 | E | C |
| ATOM | 9170 | CB | LEU | E | 596 | −1.979 | 56.870 | 49.107 | 1.00 | 13.93 | E | C |
| ATOM | 9171 | CG | LEU | E | 596 | −3.431 | 56.921 | 49.564 | 1.00 | 14.08 | E | C |
| ATOM | 9172 | CD1 | LEU | E | 596 | −3.483 | 57.035 | 51.087 | 1.00 | 11.72 | E | C |
| ATOM | 9173 | CD2 | LEU | E | 596 | −4.123 | 58.096 | 48.885 | 1.00 | 9.04 | E | C |
| ATOM | 9174 | C | LEU | E | 596 | −0.263 | 56.844 | 47.329 | 1.00 | 13.11 | E | C |
| ATOM | 9175 | O | LEU | E | 596 | 0.186 | 57.904 | 46.898 | 1.00 | 10.21 | E | O |
| ATOM | 9176 | N | ASN | E | 597 | 0.501 | 55.792 | 47.590 | 1.00 | 12.40 | E | N |
| ATOM | 9177 | CA | ASN | E | 597 | 1.937 | 55.840 | 47.397 | 1.00 | 13.74 | E | C |
| ATOM | 9178 | CB | ASN | E | 597 | 2.577 | 54.595 | 48.018 | 1.00 | 12.66 | E | C |
| ATOM | 9179 | CG | ASN | E | 597 | 2.749 | 54.727 | 49.522 | 1.00 | 15.42 | E | C |
| ATOM | 9180 | OD1 | ASN | E | 597 | 2.591 | 55.818 | 50.087 | 1.00 | 18.29 | E | O |
| ATOM | 9181 | ND2 | ASN | E | 597 | 3.075 | 53.620 | 50.180 | 1.00 | 12.97 | E | N |
| ATOM | 9182 | C | ASN | E | 597 | 2.425 | 56.035 | 45.959 | 1.00 | 14.46 | E | C |
| ATOM | 9183 | O | ASN | E | 597 | 3.633 | 56.115 | 45.726 | 1.00 | 15.42 | E | O |
| ATOM | 9184 | N | LEU | E | 598 | 1.517 | 56.105 | 44.991 | 1.00 | 11.50 | E | N |
| ATOM | 9185 | CA | LEU | E | 598 | 1.958 | 56.344 | 43.621 | 1.00 | 15.00 | E | C |
| ATOM | 9186 | CB | LEU | E | 598 | 0.789 | 56.251 | 42.637 | 1.00 | 13.49 | E | C |
| ATOM | 9187 | CG | LEU | E | 598 | 0.304 | 54.828 | 42.353 | 1.00 | 12.22 | E | C |
| ATOM | 9188 | CD1 | LEU | E | 598 | −1.007 | 54.858 | 41.583 | 1.00 | 6.69 | E | C |
| ATOM | 9189 | CD2 | LEU | E | 598 | 1.389 | 54.078 | 41.590 | 1.00 | 9.27 | E | C |
| ATOM | 9190 | C | LEU | E | 598 | 2.536 | 57.760 | 43.615 | 1.00 | 17.44 | E | C |
| ATOM | 9191 | O | LEU | E | 598 | 3.330 | 58.124 | 42.748 | 1.00 | 19.44 | E | O |
| ATOM | 9192 | N | LYS | E | 599 | 2.137 | 58.544 | 44.614 | 1.00 | 20.83 | E | N |
| ATOM | 9193 | CA | LYS | E | 599 | 2.596 | 59.921 | 44.784 | 1.00 | 23.39 | E | C |
| ATOM | 9194 | CB | LYS | E | 599 | 2.007 | 60.519 | 46.063 | 1.00 | 24.81 | E | C |
| ATOM | 9195 | CG | LYS | E | 599 | 0.789 | 61.374 | 45.851 | 1.00 | 31.79 | E | C |
| ATOM | 9196 | CD | LYS | E | 599 | 1.165 | 62.850 | 45.749 | 1.00 | 40.23 | E | C |
| ATOM | 9197 | CE | LYS | E | 599 | 0.365 | 63.569 | 44.652 | 1.00 | 39.99 | E | C |
| ATOM | 9198 | NZ | LYS | E | 599 | 1.178 | 63.779 | 43.416 | 1.00 | 40.47 | E | N |
| ATOM | 9199 | C | LYS | E | 599 | 4.109 | 59.972 | 44.904 | 1.00 | 23.93 | E | C |
| ATOM | 9200 | O | LYS | E | 599 | 4.751 | 60.925 | 44.454 | 1.00 | 24.03 | E | O |
| ATOM | 9201 | N | LYS | E | 600 | 4.675 | 58.946 | 45.527 | 1.00 | 22.96 | E | N |
| ATOM | 9202 | CA | LYS | E | 600 | 6.112 | 58.896 | 45.739 | 1.00 | 23.52 | E | C |
| ATOM | 9203 | CB | LYS | E | 600 | 6.410 | 58.118 | 47.018 | 1.00 | 24.17 | E | C |
| ATOM | 9204 | CG | LYS | E | 600 | 5.596 | 58.573 | 48.208 | 1.00 | 28.79 | E | C |
| ATOM | 9205 | CD | LYS | E | 600 | 6.011 | 57.832 | 49.462 | 1.00 | 30.60 | E | C |
| ATOM | 9206 | CE | LYS | E | 600 | 5.161 | 58.245 | 50.650 | 1.00 | 35.38 | E | C |
| ATOM | 9207 | NZ | LYS | E | 600 | 5.275 | 57.267 | 51.772 | 1.00 | 37.69 | E | N |
| ATOM | 9208 | C | LYS | E | 600 | 6.933 | 58.315 | 44.596 | 1.00 | 21.75 | E | C |
| ATOM | 9209 | O | LYS | E | 600 | 8.158 | 58.346 | 44.645 | 1.00 | 22.12 | E | O |
| ATOM | 9210 | N | SER | E | 601 | 6.275 | 57.795 | 43.566 | 1.00 | 19.98 | E | N |
| ATOM | 9211 | CA | SER | E | 601 | 7.006 | 57.200 | 42.452 | 1.00 | 20.08 | E | C |
| ATOM | 9212 | CB | SER | E | 601 | 6.886 | 55.675 | 42.497 | 1.00 | 19.27 | E | C |
| ATOM | 9213 | OG | SER | E | 601 | 7.749 | 55.078 | 41.545 | 1.00 | 17.66 | E | O |
| ATOM | 9214 | C | SER | E | 601 | 6.551 | 57.683 | 41.086 | 1.00 | 19.35 | E | C |
| ATOM | 9215 | O | SER | E | 601 | 5.506 | 57.261 | 40.590 | 1.00 | 20.73 | E | O |
| ATOM | 9216 | N | PRO | E | 602 | 7.323 | 58.585 | 40.463 | 1.00 | 17.78 | E | N |
| ATOM | 9217 | CD | PRO | E | 602 | 8.561 | 59.189 | 40.979 | 1.00 | 19.22 | E | C |
| ATOM | 9218 | CA | PRO | E | 602 | 6.972 | 59.106 | 39.137 | 1.00 | 16.50 | E | C |
| ATOM | 9219 | CB | PRO | E | 602 | 8.094 | 60.101 | 38.829 | 1.00 | 19.68 | E | C |
| ATOM | 9220 | CG | PRO | E | 602 | 9.228 | 59.701 | 39.738 | 1.00 | 19.20 | E | C |
| ATOM | 9221 | C | PRO | E | 602 | 6.900 | 57.989 | 38.096 | 1.00 | 15.48 | E | C |
| ATOM | 9222 | O | PRO | E | 602 | 6.003 | 57.965 | 37.253 | 1.00 | 15.24 | E | O |
| ATOM | 9223 | N | VAL | E | 603 | 7.841 | 57.056 | 38.164 | 1.00 | 15.53 | E | N |
| ATOM | 9224 | CA | VAL | E | 603 | 7.863 | 55.951 | 37.212 | 1.00 | 15.60 | E | C |
| ATOM | 9225 | CB | VAL | E | 603 | 9.113 | 55.056 | 37.391 | 1.00 | 14.20 | E | C |
| ATOM | 9226 | CG1 | VAL | E | 603 | 9.092 | 53.940 | 36.353 | 1.00 | 15.22 | E | C |
| ATOM | 9227 | CG2 | VAL | E | 603 | 10.382 | 55.880 | 37.236 | 1.00 | 5.51 | E | C |
| ATOM | 9228 | C | VAL | E | 603 | 6.618 | 55.082 | 37.324 | 1.00 | 14.54 | E | C |
| ATOM | 9229 | O | VAL | E | 603 | 5.957 | 54.812 | 36.318 | 1.00 | 15.37 | E | O |
| ATOM | 9230 | N | LEU | E | 604 | 6.285 | 54.652 | 38.540 | 1.00 | 13.21 | E | N |
| ATOM | 9231 | CA | LEU | E | 604 | 5.108 | 53.808 | 38.731 | 1.00 | 11.61 | E | C |
| ATOM | 9232 | CB | LEU | E | 604 | 5.097 | 53.198 | 40.132 | 1.00 | 13.20 | E | C |
| ATOM | 9233 | CG | LEU | E | 604 | 5.955 | 51.948 | 40.355 | 1.00 | 12.54 | E | C |
| ATOM | 9234 | CD1 | LEU | E | 604 | 6.185 | 51.741 | 41.851 | 1.00 | 9.93 | E | C |
| ATOM | 9235 | CD2 | LEU | E | 604 | 5.265 | 50.745 | 39.763 | 1.00 | 8.34 | E | C |
| ATOM | 9236 | C | LEU | E | 604 | 3.812 | 54.580 | 38.506 | 1.00 | 11.14 | E | C |
| ATOM | 9237 | O | LEU | E | 604 | 2.836 | 54.026 | 37.997 | 1.00 | 13.64 | E | O |
| ATOM | 9238 | N | GLN | E | 605 | 3.793 | 55.853 | 38.885 | 1.00 | 8.14 | E | N |
| ATOM | 9239 | CA | GLN | E | 605 | 2.602 | 56.671 | 38.694 | 1.00 | 8.39 | E | C |
| ATOM | 9240 | CB | GLN | E | 605 | 2.777 | 58.034 | 39.358 | 1.00 | 7.68 | E | C |
| ATOM | 9241 | CG | GLN | E | 605 | 1.528 | 58.911 | 39.318 | 1.00 | 6.84 | E | C |
| ATOM | 9242 | CD | GLN | E | 605 | 1.780 | 60.282 | 39.898 | 1.00 | 11.34 | E | C |
| ATOM | 9243 | OE1 | GLN | E | 605 | 2.585 | 60.427 | 40.824 | 1.00 | 15.01 | E | O |
| ATOM | 9244 | NE2 | GLN | E | 605 | 1.103 | 61.301 | 39.364 | 1.00 | 5.71 | E | N |
| ATOM | 9245 | C | GLN | E | 605 | 2.320 | 56.864 | 37.206 | 1.00 | 10.27 | E | C |
| ATOM | 9246 | O | GLN | E | 605 | 1.171 | 56.796 | 36.765 | 1.00 | 5.61 | E | O |
| ATOM | 9247 | N | TYR | E | 606 | 3.377 | 57.107 | 36.438 | 1.00 | 11.49 | E | N |
| ATOM | 9248 | CA | TYR | E | 606 | 3.243 | 57.297 | 34.995 | 1.00 | 12.23 | E | C |
| ATOM | 9249 | CB | TYR | E | 606 | 4.584 | 57.757 | 34.394 | 1.00 | 12.77 | E | C |
| ATOM | 9250 | CG | TYR | E | 606 | 4.496 | 58.262 | 32.965 | 1.00 | 13.93 | E | C |
| ATOM | 9251 | CD1 | TYR | E | 606 | 3.582 | 59.251 | 32.609 | 1.00 | 13.73 | E | C |
| ATOM | 9252 | CE1 | TYR | E | 606 | 3.500 | 59.717 | 31.290 | 1.00 | 14.66 | E | C |
| ATOM | 9253 | CD2 | TYR | E | 606 | 5.331 | 57.747 | 31.966 | 1.00 | 15.43 | E | C |
| ATOM | 9254 | CE2 | TYR | E | 606 | 5.258 | 58.203 | 30.645 | 1.00 | 10.81 | E | C |
| ATOM | 9255 | CZ | TYR | E | 606 | 4.343 | 59.185 | 30.315 | 1.00 | 14.36 | E | C |
| ATOM | 9256 | OH | TYR | E | 606 | 4.258 | 59.642 | 29.016 | 1.00 | 14.65 | E | O |
| ATOM | 9257 | C | TYR | E | 606 | 2.784 | 55.982 | 34.357 | 1.00 | 9.82 | E | C |
| ATOM | 9258 | O | TYR | E | 606 | 1.927 | 55.984 | 33.472 | 1.00 | 7.57 | E | O |
| ATOM | 9259 | N | LEU | E | 607 | 3.343 | 54.865 | 34.825 | 1.00 | 8.68 | E | N |
| ATOM | 9260 | CA | LEU | E | 607 | 2.985 | 53.546 | 34.297 | 1.00 | 9.83 | E | C |
| ATOM | 9261 | CB | LEU | E | 607 | 3.838 | 52.461 | 34.950 | 1.00 | 7.25 | E | C |
| ATOM | 9262 | CG | LEU | E | 607 | 5.240 | 52.317 | 34.366 | 1.00 | 8.83 | E | C |
| ATOM | 9263 | CD1 | LEU | E | 607 | 6.018 | 51.276 | 35.140 | 1.00 | 4.67 | E | C |
| ATOM | 9264 | CD2 | LEU | E | 607 | 5.133 | 51.943 | 32.899 | 1.00 | 9.89 | E | C |
| ATOM | 9265 | C | LEU | E | 607 | 1.514 | 53.234 | 34.523 | 1.00 | 8.64 | E | C |
| ATOM | 9266 | O | LEU | E | 607 | 0.875 | 52.592 | 33.697 | 1.00 | 9.67 | E | O |
| ATOM | 9267 | N | PHE | E | 608 | 0.979 | 53.689 | 35.649 | 1.00 | 11.78 | E | N |
| ATOM | 9268 | CA | PHE | E | 608 | −0.427 | 53.459 | 35.966 | 1.00 | 10.03 | E | C |
| ATOM | 9269 | CB | PHE | E | 608 | −0.700 | 53.785 | 37.439 | 1.00 | 11.23 | E | C |
| ATOM | 9270 | CG | PHE | E | 608 | −0.597 | 52.590 | 38.355 | 1.00 | 7.21 | E | C |
| ATOM | 9271 | CD1 | PHE | E | 608 | 0.624 | 51.968 | 38.570 | 1.00 | 7.00 | E | C |
| ATOM | 9272 | CD2 | PHE | E | 608 | −1.729 | 52.082 | 38.988 | 1.00 | 5.11 | E | C |
| ATOM | 9273 | CE1 | PHE | E | 608 | 0.722 | 50.853 | 39.403 | 1.00 | 7.24 | E | C |
| ATOM | 9274 | CE2 | PHE | E | 608 | −1.643 | 50.969 | 39.818 | 1.00 | 2.16 | E | C |
| ATOM | 9275 | CZ | PHE | E | 608 | −0.414 | 50.353 | 40.026 | 1.00 | 4.90 | E | C |
| ATOM | 9276 | C | PHE | E | 608 | −1.308 | 54.322 | 35.072 | 1.00 | 8.36 | E | C |
| ATOM | 9277 | O | PHE | E | 608 | −2.469 | 53.998 | 34.834 | 1.00 | 11.69 | E | O |
| ATOM | 9278 | N | PHE | E | 609 | −0.760 | 55.431 | 34.590 | 1.00 | 9.79 | E | N |
| ATOM | 9279 | CA | PHE | E | 609 | −1.499 | 56.312 | 33.694 | 1.00 | 8.98 | E | C |
| ATOM | 9280 | CB | PHE | E | 609 | −0.835 | 57.695 | 33.612 | 1.00 | 9.66 | E | C |
| ATOM | 9281 | CG | PHE | E | 609 | −1.340 | 58.535 | 32.468 | 1.00 | 11.51 | E | C |
| ATOM | 9282 | CD1 | PHE | E | 609 | −0.599 | 58.654 | 31.290 | 1.00 | 11.43 | E | C |
| ATOM | 9283 | CD2 | PHE | E | 609 | −2.584 | 59.153 | 32.540 | 1.00 | 8.70 | E | C |
| ATOM | 9284 | CE1 | PHE | E | 609 | −1.094 | 59.372 | 30.199 | 1.00 | 8.27 | E | C |
| ATOM | 9285 | CE2 | PHE | E | 609 | −3.088 | 59.872 | 31.457 | 1.00 | 8.47 | E | C |
| ATOM | 9286 | CZ | PHE | E | 609 | −2.342 | 59.982 | 30.283 | 1.00 | 7.54 | E | C |
| ATOM | 9287 | C | PHE | E | 609 | −1.496 | 55.667 | 32.306 | 1.00 | 9.67 | E | C |
| ATOM | 9288 | O | PHE | E | 609 | −2.543 | 55.512 | 31.681 | 1.00 | 9.07 | E | O |
| ATOM | 9289 | N | LEU | E | 610 | −0.309 | 55.285 | 31.840 | 1.00 | 8.16 | E | N |
| ATOM | 9290 | CA | LEU | E | 610 | −0.156 | 54.660 | 30.528 | 1.00 | 10.50 | E | C |
| ATOM | 9291 | CB | LEU | E | 610 | 1.310 | 54.311 | 30.264 | 1.00 | 7.52 | E | C |
| ATOM | 9292 | CG | LEU | E | 610 | 2.310 | 55.451 | 30.136 | 1.00 | 4.14 | E | C |
| ATOM | 9293 | CD1 | LEU | E | 610 | 3.693 | 54.866 | 29.979 | 1.00 | 2.97 | E | C |
| ATOM | 9294 | CD2 | LEU | E | 610 | 1.945 | 56.332 | 28.951 | 1.00 | 3.96 | E | C |
| ATOM | 9295 | C | LEU | E | 610 | −0.990 | 53.394 | 30.386 | 1.00 | 10.73 | E | C |
| ATOM | 9296 | O | LEU | E | 610 | −1.626 | 53.179 | 29.351 | 1.00 | 16.52 | E | O |
| ATOM | 9297 | N | ALA | E | 611 | −0.973 | 52.549 | 31.413 | 1.00 | 9.10 | E | N |
| ATOM | 9298 | CA | ALA | E | 611 | −1.739 | 51.303 | 31.396 | 1.00 | 10.10 | E | C |
| ATOM | 9299 | CB | ALA | E | 611 | −1.097 | 50.284 | 32.330 | 1.00 | 6.41 | E | C |
| ATOM | 9300 | C | ALA | E | 611 | −3.195 | 51.531 | 31.789 | 1.00 | 9.20 | E | C |
| ATOM | 9301 | O | ALA | E | 611 | −4.026 | 50.632 | 31.679 | 1.00 | 12.74 | E | O |
| ATOM | 9302 | N | GLN | E | 612 | −3.497 | 52.740 | 32.249 | 1.00 | 12.75 | E | N |
| ATOM | 9303 | CA | GLN | E | 612 | −4.851 | 53.104 | 32.665 | 1.00 | 14.05 | E | C |
| ATOM | 9304 | CB | GLN | E | 612 | −5.776 | 53.161 | 31.446 | 1.00 | 13.60 | E | C |
| ATOM | 9305 | CG | GLN | E | 612 | −5.680 | 54.463 | 30.665 | 1.00 | 12.53 | E | C |
| ATOM | 9306 | CD | GLN | E | 612 | −6.022 | 55.670 | 31.510 | 1.00 | 14.90 | E | C |
| ATOM | 9307 | OE1 | GLN | E | 612 | −7.180 | 55.887 | 31.864 | 1.00 | 13.42 | E | O |
| ATOM | 9308 | NE2 | GLN | E | 612 | −5.016 | 56.461 | 31.844 | 1.00 | 14.08 | E | N |
| ATOM | 9309 | C | GLN | E | 612 | −5.421 | 52.136 | 33.707 | 1.00 | 14.90 | E | C |
| ATOM | 9310 | O | GLN | E | 612 | −6.568 | 51.687 | 33.600 | 1.00 | 16.26 | E | O |
| ATOM | 9311 | N | ILE | E | 613 | −4.623 | 51.830 | 34.725 | 1.00 | 12.95 | E | N |
| ATOM | 9312 | CA | ILE | E | 613 | −5.055 | 50.913 | 35.770 | 1.00 | 10.67 | E | C |
| ATOM | 9313 | CB | ILE | E | 613 | −3.843 | 50.421 | 36.590 | 1.00 | 7.88 | E | C |
| ATOM | 9314 | CG2 | ILE | E | 613 | −4.275 | 49.321 | 37.550 | 1.00 | 6.31 | E | C |
| ATOM | 9315 | CG1 | ILE | E | 613 | −2.746 | 49.930 | 35.640 | 1.00 | 4.51 | E | C |
| ATOM | 9316 | CD1 | ILE | E | 613 | −1.531 | 49.295 | 36.321 | 1.00 | 7.08 | E | C |
| ATOM | 9317 | C | ILE | E | 613 | −6.072 | 51.568 | 36.708 | 1.00 | 9.23 | E | C |
| ATOM | 9318 | O | ILE | E | 613 | −5.780 | 52.568 | 37.346 | 1.00 | 11.53 | E | O |
| ATOM | 9319 | N | PRO | E | 614 | −7.292 | 51.014 | 36.787 | 1.00 | 7.24 | E | N |
| ATOM | 9320 | CD | PRO | E | 614 | −7.780 | 49.838 | 36.058 | 1.00 | 2.74 | E | C |
| ATOM | 9321 | CA | PRO | E | 614 | −8.324 | 51.574 | 37.667 | 1.00 | 6.47 | E | C |
| ATOM | 9322 | CB | PRO | E | 614 | −9.513 | 50.638 | 37.465 | 1.00 | 3.92 | E | C |
| ATOM | 9323 | CG | PRO | E | 614 | −9.255 | 49.970 | 36.181 | 1.00 | 2.91 | E | C |
| ATOM | 9324 | C | PRO | E | 614 | −7.870 | 51.604 | 39.132 | 1.00 | 7.46 | E | C |
| ATOM | 9325 | O | PRO | E | 614 | −7.282 | 50.648 | 39.634 | 1.00 | 3.47 | E | O |
| ATOM | 9326 | N | ILE | E | 615 | −8.146 | 52.711 | 39.810 | 1.00 | 10.02 | E | N |
| ATOM | 9327 | CA | ILE | E | 615 | −7.766 | 52.872 | 41.210 | 1.00 | 10.50 | E | C |
| ATOM | 9328 | CB | ILE | E | 615 | −6.650 | 53.928 | 41.371 | 1.00 | 10.90 | E | C |
| ATOM | 9329 | CG2 | ILE | E | 615 | −6.289 | 54.097 | 42.839 | 1.00 | 12.50 | E | C |
| ATOM | 9330 | CG1 | ILE | E | 615 | −5.411 | 53.509 | 40.579 | 1.00 | 12.03 | E | C |
| ATOM | 9331 | CD1 | ILE | E | 615 | −4.429 | 54.653 | 40.355 | 1.00 | 9.72 | E | C |
| ATOM | 9332 | C | ILE | E | 615 | −8.964 | 53.333 | 42.027 | 1.00 | 11.96 | E | C |
| ATOM | 9333 | O | ILE | E | 615 | −9.517 | 54.399 | 41.756 | 1.00 | 12.23 | E | O |
| ATOM | 9334 | N | ALA | E | 616 | −9.384 | 52.531 | 43.007 | 1.00 | 12.77 | E | N |
| ATOM | 9335 | CA | ALA | E | 616 | −10.519 | 52.922 | 43.850 | 1.00 | 11.92 | E | C |
| ATOM | 9336 | CB | ALA | E | 616 | −11.287 | 51.691 | 44.311 | 1.00 | 9.65 | E | C |
| ATOM | 9337 | C | ALA | E | 616 | −9.985 | 53.694 | 45.059 | 1.00 | 12.06 | E | C |
| ATOM | 9338 | O | ALA | E | 616 | −9.298 | 53.125 | 45.922 | 1.00 | 9.35 | E | O |
| ATOM | 9339 | N | MET | E | 617 | −10.292 | 54.987 | 45.125 | 1.00 | 10.10 | E | N |
| ATOM | 9340 | CA | MET | E | 617 | −9.817 | 55.803 | 46.230 | 1.00 | 8.05 | E | C |
| ATOM | 9341 | CB | MET | E | 617 | −9.274 | 57.130 | 45.705 | 1.00 | 10.31 | E | C |
| ATOM | 9342 | CG | MET | E | 617 | −8.366 | 56.990 | 44.476 | 1.00 | 14.55 | E | C |
| ATOM | 9343 | SD | MET | E | 617 | −6.960 | 58.140 | 44.487 | 1.00 | 15.43 | E | S |
| ATOM | 9344 | CE | MET | E | 617 | −7.563 | 59.313 | 43.437 | 1.00 | 20.93 | E | C |
| ATOM | 9345 | C | MET | E | 617 | −10.897 | 56.052 | 47.271 | 1.00 | 9.36 | E | C |
| ATOM | 9346 | O | MET | E | 617 | −12.095 | 55.956 | 46.981 | 1.00 | 6.91 | E | O |
| ATOM | 9347 | N | SER | E | 618 | −10.450 | 56.371 | 48.489 | 1.00 | 13.42 | E | N |
| ATOM | 9348 | CA | SER | E | 618 | −11.326 | 56.637 | 49.638 | 1.00 | 12.76 | E | C |
| ATOM | 9349 | CB | SER | E | 618 | −11.494 | 55.374 | 50.479 | 1.00 | 10.37 | E | C |
| ATOM | 9350 | OG | SER | E | 618 | −11.689 | 54.230 | 49.666 | 1.00 | 10.99 | E | O |
| ATOM | 9351 | C | SER | E | 618 | −10.721 | 57.709 | 50.524 | 1.00 | 11.12 | E | C |
| ATOM | 9352 | O | SER | E | 618 | −10.128 | 57.398 | 51.545 | 1.00 | 14.32 | E | O |
| ATOM | 9353 | N | PRO | E | 619 | −10.842 | 58.983 | 50.139 | 1.00 | 12.95 | E | N |
| ATOM | 9354 | CD | PRO | E | 619 | −11.467 | 59.459 | 48.894 | 1.00 | 13.90 | E | C |
| ATOM | 9355 | CA | PRO | E | 619 | −10.291 | 60.091 | 50.929 | 1.00 | 12.63 | E | C |
| ATOM | 9356 | CB | PRO | E | 619 | −10.680 | 61.331 | 50.131 | 1.00 | 12.49 | E | C |
| ATOM | 9357 | CG | PRO | E | 619 | −10.876 | 60.830 | 48.735 | 1.00 | 13.93 | E | C |
| ATOM | 9358 | C | PRO | E | 619 | −10.735 | 60.185 | 52.391 | 1.00 | 13.77 | E | C |
| ATOM | 9359 | O | PRO | E | 619 | −9.931 | 60.544 | 53.241 | 1.00 | 16.91 | E | O |
| ATOM | 9360 | N | LEU | E | 620 | −11.995 | 59.871 | 52.691 | 1.00 | 15.24 | E | N |
| ATOM | 9361 | CA | LEU | E | 620 | −12.483 | 59.945 | 54.076 | 1.00 | 13.23 | E | C |
| ATOM | 9362 | CB | LEU | E | 620 | −14.006 | 59.794 | 54.120 | 1.00 | 12.49 | E | C |
| ATOM | 9363 | CG | LEU | E | 620 | −14.764 | 61.058 | 53.685 | 1.00 | 15.70 | E | C |
| ATOM | 9364 | CD1 | LEU | E | 620 | −16.260 | 60.793 | 53.585 | 1.00 | 10.95 | E | C |
| ATOM | 9365 | CD2 | LEU | E | 620 | −14.482 | 62.170 | 54.681 | 1.00 | 14.47 | E | C |
| ATOM | 9366 | C | LEU | E | 620 | −11.832 | 58.880 | 54.952 | 1.00 | 15.39 | E | C |
| ATOM | 9367 | O | LEU | E | 620 | −11.480 | 59.136 | 56.110 | 1.00 | 17.57 | E | O |
| ATOM | 9368 | N | SER | E | 621 | −11.670 | 57.685 | 54.400 | 1.00 | 14.95 | E | N |
| ATOM | 9369 | CA | SER | E | 621 | −11.033 | 56.604 | 55.124 | 1.00 | 12.41 | E | C |
| ATOM | 9370 | CB | SER | E | 621 | −11.133 | 55.320 | 54.314 | 1.00 | 14.41 | E | C |
| ATOM | 9371 | OG | SER | E | 621 | −10.306 | 54.307 | 54.836 | 1.00 | 16.75 | E | O |
| ATOM | 9372 | C | SER | E | 621 | −9.573 | 56.978 | 55.369 | 1.00 | 17.04 | E | C |
| ATOM | 9373 | O | SER | E | 621 | −9.075 | 56.840 | 56.486 | 1.00 | 16.58 | E | O |
| ATOM | 9374 | N | ASN | E | 622 | −8.890 | 57.477 | 54.334 | 1.00 | 17.52 | E | N |
| ATOM | 9375 | CA | ASN | E | 622 | −7.482 | 57.874 | 54.463 | 1.00 | 16.28 | E | C |
| ATOM | 9376 | CB | ASN | E | 622 | −6.928 | 58.380 | 53.127 | 1.00 | 16.21 | E | C |
| ATOM | 9377 | CG | ASN | E | 622 | −7.061 | 57.369 | 52.004 | 1.00 | 18.12 | E | C |
| ATOM | 9378 | OD1 | ASN | E | 622 | −7.116 | 57.746 | 50.832 | 1.00 | 19.32 | E | O |
| ATOM | 9379 | ND2 | ASN | E | 622 | −7.102 | 56.085 | 52.348 | 1.00 | 16.03 | E | N |
| ATOM | 9380 | C | ASN | E | 622 | −7.301 | 58.981 | 55.503 | 1.00 | 16.13 | E | C |
| ATOM | 9381 | O | ASN | E | 622 | −6.324 | 58.998 | 56.252 | 1.00 | 16.92 | E | O |
| ATOM | 9382 | N | ASN | E | 623 | −8.242 | 59.915 | 55.529 | 1.00 | 15.58 | E | N |
| ATOM | 9383 | CA | ASN | E | 623 | −8.208 | 61.035 | 56.463 | 1.00 | 20.99 | E | C |
| ATOM | 9384 | CB | ASN | E | 623 | −9.365 | 61.990 | 56.134 | 1.00 | 19.17 | E | C |
| ATOM | 9385 | CG | ASN | E | 623 | −9.492 | 63.140 | 57.116 | 1.00 | 19.77 | E | C |
| ATOM | 9386 | OD1 | ASN | E | 623 | −10.511 | 63.269 | 57.799 | 1.00 | 18.32 | E | O |
| ATOM | 9387 | ND2 | ASN | E | 623 | −8.470 | 63.990 | 57.181 | 1.00 | 15.11 | E | N |
| ATOM | 9388 | C | ASN | E | 623 | −8.305 | 60.540 | 57.906 | 1.00 | 26.03 | E | C |
| ATOM | 9389 | O | ASN | E | 623 | −7.767 | 61.148 | 58.819 | 1.00 | 26.58 | E | O |
| ATOM | 9390 | N | SER | E | 624 | −8.987 | 59.420 | 58.100 | 1.00 | 30.65 | E | N |
| ATOM | 9391 | CA | SER | E | 624 | −9.153 | 58.852 | 59.425 | 1.00 | 34.43 | E | C |
| ATOM | 9392 | CB | SER | E | 624 | −10.517 | 58.182 | 59.532 | 1.00 | 35.52 | E | C |
| ATOM | 9393 | OG | SER | E | 624 | −11.273 | 58.739 | 60.586 | 1.00 | 40.32 | E | O |
| ATOM | 9394 | C | SER | E | 624 | −8.092 | 57.813 | 59.738 | 1.00 | 37.67 | E | C |
| ATOM | 9395 | O | SER | E | 624 | −7.999 | 57.346 | 60.875 | 1.00 | 41.71 | E | O |
| ATOM | 9396 | N | LEU | E | 625 | −7.280 | 57.465 | 58.747 | 1.00 | 40.50 | E | N |
| ATOM | 9397 | CA | LEU | E | 625 | −6.284 | 56.422 | 58.942 | 1.00 | 42.38 | E | C |
| ATOM | 9398 | CB | LEU | E | 625 | −6.710 | 55.203 | 58.112 | 1.00 | 45.11 | E | C |
| ATOM | 9399 | CG | LEU | E | 625 | −7.000 | 53.854 | 58.784 | 1.00 | 47.74 | E | C |
| ATOM | 9400 | CD1 | LEU | E | 625 | −6.275 | 53.777 | 60.115 | 1.00 | 51.97 | E | C |
| ATOM | 9401 | CD2 | LEU | E | 625 | −8.487 | 53.672 | 58.989 | 1.00 | 44.64 | E | C |
| ATOM | 9402 | C | LEU | E | 625 | −4.805 | 56.750 | 58.657 | 1.00 | 40.95 | E | C |
| ATOM | 9403 | O | LEU | E | 625 | −3.947 | 56.466 | 59.485 | 1.00 | 41.44 | E | O |
| ATOM | 9404 | N | PHE | E | 626 | −4.503 | 57.341 | 57.503 | 1.00 | 40.04 | E | N |
| ATOM | 9405 | CA | PHE | E | 626 | −3.110 | 57.619 | 57.152 | 1.00 | 39.18 | E | C |
| ATOM | 9406 | CB | PHE | E | 626 | −2.623 | 56.569 | 56.147 | 1.00 | 39.68 | E | C |
| ATOM | 9407 | CG | PHE | E | 626 | −2.563 | 55.166 | 56.695 | 1.00 | 40.31 | E | C |
| ATOM | 9408 | CD1 | PHE | E | 626 | −1.426 | 54.712 | 57.362 | 1.00 | 39.32 | E | C |
| ATOM | 9409 | CD2 | PHE | E | 626 | −3.632 | 54.287 | 56.517 | 1.00 | 42.35 | E | C |
| ATOM | 9410 | CE1 | PHE | E | 626 | −1.355 | 53.401 | 57.844 | 1.00 | 40.90 | E | C |
| ATOM | 9411 | CE2 | PHE | E | 626 | −3.574 | 52.971 | 56.995 | 1.00 | 39.79 | E | C |
| ATOM | 9412 | CZ | PHE | E | 626 | −2.434 | 52.528 | 57.660 | 1.00 | 41.09 | E | C |
| ATOM | 9413 | C | PHE | E | 626 | −2.764 | 59.006 | 56.594 | 1.00 | 37.11 | E | C |
| ATOM | 9414 | O | PHE | E | 626 | −1.664 | 59.494 | 56.825 | 1.00 | 36.67 | E | O |
| ATOM | 9415 | N | LEU | E | 627 | −3.686 | 59.633 | 55.863 | 1.00 | 37.33 | E | N |
| ATOM | 9416 | CA | LEU | E | 627 | −3.422 | 60.940 | 55.258 | 1.00 | 33.13 | E | C |
| ATOM | 9417 | CB | LEU | E | 627 | −3.226 | 60.776 | 53.749 | 1.00 | 31.67 | E | C |
| ATOM | 9418 | CG | LEU | E | 627 | −2.025 | 61.374 | 53.017 | 1.00 | 31.97 | E | C |
| ATOM | 9419 | CD1 | LEU | E | 627 | −2.436 | 61.641 | 51.578 | 1.00 | 30.67 | E | C |
| ATOM | 9420 | CD2 | LEU | E | 627 | −1.544 | 62.647 | 53.684 | 1.00 | 28.59 | E | C |
| ATOM | 9421 | C | LEU | E | 627 | −4.540 | 61.944 | 55.491 | 1.00 | 31.42 | E | C |
| ATOM | 9422 | O | LEU | E | 627 | −5.709 | 61.643 | 55.270 | 1.00 | 33.34 | E | O |
| ATOM | 9423 | N | GLU | E | 628 | −4.172 | 63.146 | 55.915 | 1.00 | 30.20 | E | N |
| ATOM | 9424 | CA | GLU | E | 628 | −5.142 | 64.208 | 56.161 | 1.00 | 29.60 | E | C |
| ATOM | 9425 | CB | GLU | E | 628 | −4.412 | 65.432 | 56.720 | 1.00 | 32.84 | E | C |
| ATOM | 9426 | CG | GLU | E | 628 | −5.013 | 66.769 | 56.364 | 1.00 | 41.68 | E | C |
| ATOM | 9427 | CD | GLU | E | 628 | −4.092 | 67.927 | 56.709 | 1.00 | 47.03 | E | C |
| ATOM | 9428 | OE1 | GLU | E | 628 | −2.929 | 67.676 | 57.090 | 1.00 | 49.74 | E | O |
| ATOM | 9429 | OE2 | GLU | E | 628 | −4.534 | 69.091 | 56.597 | 1.00 | 50.57 | E | O |
| ATOM | 9430 | C | GLU | E | 628 | −5.862 | 64.540 | 54.847 | 1.00 | 27.26 | E | C |
| ATOM | 9431 | O | GLU | E | 628 | −5.235 | 64.602 | 53.790 | 1.00 | 27.73 | E | O |
| ATOM | 9432 | N | TYR | E | 629 | −7.172 | 64.758 | 54.914 | 1.00 | 23.38 | E | N |
| ATOM | 9433 | CA | TYR | E | 629 | −7.966 | 65.034 | 53.719 | 1.00 | 23.38 | E | C |
| ATOM | 9434 | CB | TYR | E | 629 | −9.361 | 65.547 | 54.092 | 1.00 | 18.08 | E | C |
| ATOM | 9435 | CG | TYR | E | 629 | −10.388 | 65.208 | 53.032 | 1.00 | 18.01 | E | C |
| ATOM | 9436 | CD1 | TYR | E | 629 | −10.550 | 66.010 | 51.902 | 1.00 | 17.51 | E | C |
| ATOM | 9437 | CE1 | TYR | E | 629 | −11.432 | 65.648 | 50.885 | 1.00 | 17.92 | E | C |
| ATOM | 9438 | CD2 | TYR | E | 629 | −11.143 | 64.043 | 53.117 | 1.00 | 16.68 | E | C |
| ATOM | 9439 | CE2 | TYR | E | 629 | −12.023 | 63.676 | 52.109 | 1.00 | 16.06 | E | C |
| ATOM | 9440 | CZ | TYR | E | 629 | −12.161 | 64.476 | 50.997 | 1.00 | 17.74 | E | C |
| ATOM | 9441 | OH | TYR | E | 629 | −13.008 | 64.081 | 49.989 | 1.00 | 19.85 | E | O |
| ATOM | 9442 | C | TYR | E | 629 | −7.372 | 65.972 | 52.669 | 1.00 | 25.58 | E | C |
| ATOM | 9443 | O | TYR | E | 629 | −7.154 | 65.572 | 51.522 | 1.00 | 23.80 | E | O |
| ATOM | 9444 | N | ALA | E | 630 | −7.116 | 67.217 | 53.056 | 1.00 | 27.14 | E | N |
| ATOM | 9445 | CA | ALA | E | 630 | −6.588 | 68.208 | 52.127 | 1.00 | 24.70 | E | C |
| ATOM | 9446 | CB | ALA | E | 630 | −6.471 | 69.563 | 52.824 | 1.00 | 23.85 | E | C |
| ATOM | 9447 | C | ALA | E | 630 | −5.257 | 67.830 | 51.485 | 1.00 | 25.74 | E | C |
| ATOM | 9448 | O | ALA | E | 630 | −4.802 | 68.507 | 50.567 | 1.00 | 28.58 | E | O |
| ATOM | 9449 | N | LYS | E | 631 | −4.638 | 66.751 | 51.951 | 1.00 | 24.05 | E | N |
| ATOM | 9450 | CA | LYS | E | 631 | −3.358 | 66.321 | 51.395 | 1.00 | 21.89 | E | C |
| ATOM | 9451 | CB | LYS | E | 631 | −2.385 | 65.973 | 52.528 | 1.00 | 25.40 | E | C |
| ATOM | 9452 | CG | LYS | E | 631 | −1.599 | 67.159 | 53.098 | 1.00 | 30.15 | E | C |
| ATOM | 9453 | CD | LYS | E | 631 | −2.408 | 68.451 | 53.070 | 1.00 | 36.49 | E | C |
| ATOM | 9454 | CE | LYS | E | 631 | −1.510 | 69.689 | 53.043 | 1.00 | 41.23 | E | C |
| ATOM | 9455 | NZ | LYS | E | 631 | −2.034 | 70.799 | 53.906 | 1.00 | 43.93 | E | N |
| ATOM | 9456 | C | LYS | E | 631 | −3.529 | 65.110 | 50.480 | 1.00 | 20.94 | E | C |
| ATOM | 9457 | O | LYS | E | 631 | −2.548 | 64.561 | 49.977 | 1.00 | 20.30 | E | O |
| ATOM | 9458 | N | ASN | E | 632 | −4.774 | 64.694 | 50.261 | 1.00 | 18.52 | E | N |
| ATOM | 9459 | CA | ASN | E | 632 | −5.043 | 63.536 | 49.410 | 1.00 | 18.17 | E | C |
| ATOM | 9460 | CB | ASN | E | 632 | −6.505 | 63.104 | 49.547 | 1.00 | 15.49 | E | C |
| ATOM | 9461 | CG | ASN | E | 632 | −6.711 | 61.657 | 49.178 | 1.00 | 14.27 | E | C |
| ATOM | 9462 | OD1 | ASN | E | 632 | −6.881 | 60.806 | 50.044 | 1.00 | 16.80 | E | O |
| ATOM | 9463 | ND2 | ASN | E | 632 | −6.689 | 61.367 | 47.884 | 1.00 | 13.20 | E | N |
| ATOM | 9464 | C | ASN | E | 632 | −4.722 | 63.767 | 47.934 | 1.00 | 15.26 | E | C |
| ATOM | 9465 | O | ASN | E | 632 | −5.097 | 64.784 | 47.361 | 1.00 | 15.75 | E | O |
| ATOM | 9466 | N | PRO | E | 633 | −4.015 | 62.818 | 47.301 | 1.00 | 15.98 | E | N |
| ATOM | 9467 | CD | PRO | E | 633 | −3.473 | 61.570 | 47.877 | 1.00 | 16.21 | E | C |
| ATOM | 9468 | CA | PRO | E | 633 | −3.667 | 62.966 | 45.884 | 1.00 | 15.09 | E | C |
| ATOM | 9469 | CB | PRO | E | 633 | −2.539 | 61.959 | 45.682 | 1.00 | 13.65 | E | C |
| ATOM | 9470 | CG | PRO | E | 633 | −2.765 | 60.920 | 46.722 | 1.00 | 14.93 | E | C |
| ATOM | 9471 | C | PRO | E | 633 | −4.834 | 62.722 | 44.922 | 1.00 | 14.93 | E | C |
| ATOM | 9472 | O | PRO | E | 633 | −4.646 | 62.706 | 43.715 | 1.00 | 14.32 | E | O |
| ATOM | 9473 | N | PHE | E | 634 | −6.037 | 62.548 | 45.452 | 1.00 | 15.34 | E | N |
| ATOM | 9474 | CA | PHE | E | 634 | −7.202 | 62.295 | 44.610 | 1.00 | 15.26 | E | C |
| ATOM | 9475 | CB | PHE | E | 634 | −8.487 | 62.271 | 45.456 | 1.00 | 13.05 | E | C |
| ATOM | 9476 | CG | PHE | E | 634 | −9.753 | 62.237 | 44.632 | 1.00 | 14.23 | E | C |
| ATOM | 9477 | CD1 | PHE | E | 634 | −10.405 | 63.417 | 44.287 | 1.00 | 11.79 | E | C |
| ATOM | 9478 | CD2 | PHE | E | 634 | −10.259 | 61.033 | 44.155 | 1.00 | 14.83 | E | C |
| ATOM | 9479 | CE1 | PHE | E | 634 | −11.536 | 63.403 | 43.476 | 1.00 | 12.23 | E | C |
| ATOM | 9480 | CE2 | PHE | E | 634 | −11.396 | 61.007 | 43.338 | 1.00 | 17.25 | E | C |
| ATOM | 9481 | CZ | PHE | E | 634 | −12.033 | 62.200 | 42.998 | 1.00 | 13.44 | E | C |
| ATOM | 9482 | C | PHE | E | 634 | −7.368 | 63.289 | 43.457 | 1.00 | 16.64 | E | C |
| ATOM | 9483 | O | PHE | E | 634 | −7.531 | 62.882 | 42.305 | 1.00 | 17.71 | E | O |
| ATOM | 9484 | N | LEU | E | 635 | −7.342 | 64.583 | 43.756 | 1.00 | 13.93 | E | N |
| ATOM | 9485 | CA | LEU | E | 635 | −7.496 | 65.596 | 42.714 | 1.00 | 12.95 | E | C |
| ATOM | 9486 | CB | LEU | E | 635 | −7.551 | 66.989 | 43.331 | 1.00 | 7.92 | E | C |
| ATOM | 9487 | CG | LEU | E | 635 | −7.827 | 68.136 | 42.363 | 1.00 | 10.20 | E | C |
| ATOM | 9488 | CD1 | LEU | E | 635 | −9.192 | 67.944 | 41.724 | 1.00 | 10.27 | E | C |
| ATOM | 9489 | CD2 | LEU | E | 635 | −7.764 | 69.455 | 43.095 | 1.00 | 4.45 | E | C |
| ATOM | 9490 | C | LEU | E | 635 | −6.342 | 65.532 | 41.711 | 1.00 | 14.51 | E | C |
| ATOM | 9491 | O | LEU | E | 635 | −6.561 | 65.469 | 40.497 | 1.00 | 17.88 | E | O |
| ATOM | 9492 | N | ASP | E | 636 | −5.115 | 65.548 | 42.218 | 1.00 | 11.03 | E | N |
| ATOM | 9493 | CA | ASP | E | 636 | −3.938 | 65.484 | 41.360 | 1.00 | 11.71 | E | C |
| ATOM | 9494 | CB | ASP | E | 636 | −2.687 | 65.272 | 42.215 | 1.00 | 10.25 | E | C |
| ATOM | 9495 | CG | ASP | E | 636 | −1.410 | 65.511 | 41.448 | 1.00 | 13.30 | E | C |
| ATOM | 9496 | OD1 | ASP | E | 636 | −1.288 | 66.567 | 40.797 | 1.00 | 13.97 | E | O |
| ATOM | 9497 | OD2 | ASP | E | 636 | −0.520 | 64.640 | 41.500 | 1.00 | 15.03 | E | O |
| ATOM | 9498 | C | ASP | E | 636 | −4.069 | 64.348 | 40.350 | 1.00 | 11.64 | E | C |
| ATOM | 9499 | O | ASP | E | 636 | −3.918 | 64.549 | 39.143 | 1.00 | 12.18 | E | O |
| ATOM | 9500 | N | PHE | E | 637 | −4.359 | 63.156 | 40.853 | 1.00 | 9.18 | E | N |
| ATOM | 9501 | CA | PHE | E | 637 | −4.512 | 61.982 | 40.007 | 1.00 | 10.90 | E | C |
| ATOM | 9502 | CB | PHE | E | 637 | −4.784 | 60.746 | 40.874 | 1.00 | 8.34 | E | C |
| ATOM | 9503 | CG | PHE | E | 637 | −3.589 | 60.277 | 41.676 | 1.00 | 7.86 | E | C |
| ATOM | 9504 | CD1 | PHE | E | 637 | −2.377 | 60.966 | 41.634 | 1.00 | 6.95 | E | C |
| ATOM | 9505 | CD2 | PHE | E | 637 | −3.673 | 59.128 | 42.459 | 1.00 | 6.00 | E | C |
| ATOM | 9506 | CE1 | PHE | E | 637 | −1.270 | 60.510 | 42.358 | 1.00 | 6.65 | E | C |
| ATOM | 9507 | CE2 | PHE | E | 637 | −2.576 | 58.665 | 43.182 | 1.00 | 3.17 | E | C |
| ATOM | 9508 | CZ | PHE | E | 637 | −1.375 | 59.353 | 43.132 | 1.00 | 5.91 | E | C |
| ATOM | 9509 | C | PHE | E | 637 | −5.644 | 62.170 | 38.990 | 1.00 | 12.11 | E | C |
| ATOM | 9510 | O | PHE | E | 637 | −5.497 | 61.841 | 37.814 | 1.00 | 13.24 | E | O |
| ATOM | 9511 | N | LEU | E | 638 | −6.772 | 62.706 | 39.436 | 1.00 | 11.35 | E | N |
| ATOM | 9512 | CA | LEU | E | 638 | −7.898 | 62.915 | 38.540 | 1.00 | 12.28 | E | C |
| ATOM | 9513 | CB | LEU | E | 638 | −9.105 | 63.443 | 39.312 | 1.00 | 15.28 | E | C |
| ATOM | 9514 | CG | LEU | E | 638 | −10.350 | 63.646 | 38.442 | 1.00 | 17.54 | E | C |
| ATOM | 9515 | CD1 | LEU | E | 638 | −11.081 | 62.331 | 38.309 | 1.00 | 15.32 | E | C |
| ATOM | 9516 | CD2 | LEU | E | 638 | −11.255 | 64.701 | 39.037 | 1.00 | 15.75 | E | C |
| ATOM | 9517 | C | LEU | E | 638 | −7.574 | 63.879 | 37.398 | 1.00 | 15.02 | E | C |
| ATOM | 9518 | O | LEU | E | 638 | −7.896 | 63.617 | 36.240 | 1.00 | 15.17 | E | O |
| ATOM | 9519 | N | GLN | E | 639 | −6.948 | 65.002 | 37.723 | 1.00 | 15.13 | E | N |
| ATOM | 9520 | CA | GLN | E | 639 | −6.601 | 65.990 | 36.709 | 1.00 | 13.63 | E | C |
| ATOM | 9521 | CB | GLN | E | 639 | −6.019 | 67.235 | 37.377 | 1.00 | 14.25 | E | C |
| ATOM | 9522 | CG | GLN | E | 639 | −7.024 | 68.036 | 38.185 | 1.00 | 10.61 | E | C |
| ATOM | 9523 | CD | GLN | E | 639 | −6.388 | 69.220 | 38.862 | 1.00 | 12.80 | E | C |
| ATOM | 9524 | OE1 | GLN | E | 639 | −5.233 | 69.160 | 39.275 | 1.00 | 13.14 | E | O |
| ATOM | 9525 | NE2 | GLN | E | 639 | −7.134 | 70.309 | 38.979 | 1.00 | 13.89 | E | N |
| ATOM | 9526 | C | GLN | E | 639 | −5.595 | 65.433 | 35.707 | 1.00 | 14.04 | E | C |
| ATOM | 9527 | O | GLN | E | 639 | −5.724 | 65.633 | 34.505 | 1.00 | 13.50 | E | O |
| ATOM | 9528 | N | LYS | E | 640 | −4.587 | 64.740 | 36.220 | 1.00 | 13.65 | E | N |
| ATOM | 9529 | CA | LYS | E | 640 | −3.543 | 64.158 | 35.394 | 1.00 | 12.99 | E | C |
| ATOM | 9530 | CB | LYS | E | 640 | −2.468 | 63.530 | 36.283 | 1.00 | 10.63 | E | C |
| ATOM | 9531 | CG | LYS | E | 640 | −1.582 | 64.536 | 36.967 | 1.00 | 4.94 | E | C |
| ATOM | 9532 | CD | LYS | E | 640 | −0.477 | 63.837 | 37.688 | 1.00 | 5.31 | E | C |
| ATOM | 9533 | CE | LYS | E | 640 | 0.375 | 64.808 | 38.476 | 1.00 | 3.08 | E | C |
| ATOM | 9534 | NZ | LYS | E | 640 | 1.165 | 64.034 | 39.465 | 1.00 | 9.09 | E | N |
| ATOM | 9535 | C | LYS | E | 640 | −4.076 | 63.113 | 34.425 | 1.00 | 13.29 | E | C |
| ATOM | 9536 | O | LYS | E | 640 | −3.458 | 62.848 | 33.386 | 1.00 | 14.65 | E | O |
| ATOM | 9537 | N | GLY | E | 641 | −5.203 | 62.499 | 34.776 | 1.00 | 13.61 | E | N |
| ATOM | 9538 | CA | GLY | E | 641 | −5.798 | 61.500 | 33.908 | 1.00 | 11.69 | E | C |
| ATOM | 9539 | C | GLY | E | 641 | −5.761 | 60.044 | 34.343 | 1.00 | 13.21 | E | C |
| ATOM | 9540 | O | GLY | E | 641 | −6.145 | 59.170 | 33.564 | 1.00 | 11.75 | E | O |
| ATOM | 9541 | N | LEU | E | 642 | −5.305 | 59.756 | 35.561 | 1.00 | 13.04 | E | N |
| ATOM | 9542 | CA | LEU | E | 642 | −5.262 | 58.365 | 36.015 | 1.00 | 11.25 | E | C |
| ATOM | 9543 | CB | LEU | E | 642 | −4.519 | 58.242 | 37.355 | 1.00 | 12.32 | E | C |
| ATOM | 9544 | CG | LEU | E | 642 | −3.060 | 58.691 | 37.603 | 1.00 | 13.98 | E | C |
| ATOM | 9545 | CD1 | LEU | E | 642 | −2.303 | 57.528 | 38.203 | 1.00 | 9.57 | E | C |
| ATOM | 9546 | CD2 | LEU | E | 642 | −2.368 | 59.180 | 36.353 | 1.00 | 12.86 | E | C |
| ATOM | 9547 | C | LEU | E | 642 | −6.699 | 57.859 | 36.165 | 1.00 | 9.36 | E | C |
| ATOM | 9548 | O | LEU | E | 642 | −7.608 | 58.641 | 36.420 | 1.00 | 9.82 | E | O |
| ATOM | 9549 | N | MET | E | 643 | −6.898 | 56.554 | 36.006 | 1.00 | 9.88 | E | N |
| ATOM | 9550 | CA | MET | E | 643 | −8.227 | 55.950 | 36.101 | 1.00 | 12.30 | E | C |
| ATOM | 9551 | CB | MET | E | 643 | −8.177 | 54.539 | 35.513 | 1.00 | 16.19 | E | C |
| ATOM | 9552 | CG | MET | E | 643 | −9.232 | 54.259 | 34.467 | 1.00 | 19.09 | E | C |
| ATOM | 9553 | SD | MET | E | 643 | −10.755 | 53.721 | 35.235 | 1.00 | 28.65 | E | S |
| ATOM | 9554 | CE | MET | E | 643 | −11.429 | 52.679 | 33.915 | 1.00 | 21.71 | E | C |
| ATOM | 9555 | C | MET | E | 643 | −8.734 | 55.902 | 37.545 | 1.00 | 13.98 | E | C |
| ATOM | 9556 | O | MET | E | 643 | −8.532 | 54.908 | 38.251 | 1.00 | 12.81 | E | O |
| ATOM | 9557 | N | ILE | E | 644 | −9.428 | 56.957 | 37.969 | 1.00 | 12.61 | E | N |
| ATOM | 9558 | CA | ILE | E | 644 | −9.912 | 57.060 | 39.352 | 1.00 | 11.48 | E | C |
| ATOM | 9559 | CB | ILE | E | 644 | −9.478 | 58.419 | 39.965 | 1.00 | 11.62 | E | C |
| ATOM | 9560 | CG2 | ILE | E | 644 | −9.901 | 58.501 | 41.401 | 1.00 | 12.64 | E | C |
| ATOM | 9561 | CG1 | ILE | E | 644 | −7.972 | 58.620 | 39.819 | 1.00 | 10.43 | E | C |
| ATOM | 9562 | CD1 | ILE | E | 644 | −7.148 | 57.540 | 40.445 | 1.00 | 16.13 | E | C |
| ATOM | 9563 | C | ILE | E | 644 | −11.415 | 56.943 | 39.630 | 1.00 | 10.63 | E | C |
| ATOM | 9564 | O | ILE | E | 644 | −12.237 | 57.455 | 38.878 | 1.00 | 12.13 | E | O |
| ATOM | 9565 | N | SER | E | 645 | −11.763 | 56.270 | 40.723 | 1.00 | 9.91 | E | N |
| ATOM | 9566 | CA | SER | E | 645 | −13.156 | 56.175 | 41.161 | 1.00 | 10.44 | E | C |
| ATOM | 9567 | CB | SER | E | 645 | −13.789 | 54.817 | 40.796 | 1.00 | 8.42 | E | C |
| ATOM | 9568 | OG | SER | E | 645 | −13.297 | 53.737 | 41.566 | 1.00 | 10.19 | E | O |
| ATOM | 9569 | C | SER | E | 645 | −13.173 | 56.419 | 42.686 | 1.00 | 12.13 | E | C |
| ATOM | 9570 | O | SER | E | 645 | −12.145 | 56.278 | 43.359 | 1.00 | 8.62 | E | O |
| ATOM | 9571 | N | LEU | E | 646 | −14.323 | 56.816 | 43.219 | 1.00 | 11.22 | E | N |
| ATOM | 9572 | CA | LEU | E | 646 | −14.438 | 57.095 | 44.643 | 1.00 | 11.35 | E | C |
| ATOM | 9573 | CB | LEU | E | 646 | −15.214 | 58.401 | 44.871 | 1.00 | 5.75 | E | C |
| ATOM | 9574 | CG | LEU | E | 646 | −14.409 | 59.701 | 44.752 | 1.00 | 8.25 | E | C |
| ATOM | 9575 | CD1 | LEU | E | 646 | −15.327 | 60.877 | 44.902 | 1.00 | 5.90 | E | C |
| ATOM | 9576 | CD2 | LEU | E | 646 | −13.315 | 59.761 | 45.814 | 1.00 | 5.85 | E | C |
| ATOM | 9577 | C | LEU | E | 646 | −15.135 | 55.942 | 45.352 | 1.00 | 14.32 | E | C |
| ATOM | 9578 | O | LEU | E | 646 | −16.125 | 55.403 | 44.852 | 1.00 | 14.51 | E | O |
| ATOM | 9579 | N | SER | E | 647 | −14.601 | 55.557 | 46.509 | 1.00 | 14.90 | E | N |
| ATOM | 9580 | CA | SER | E | 647 | −15.187 | 54.478 | 47.288 | 1.00 | 15.28 | E | C |
| ATOM | 9581 | CB | SER | E | 647 | −14.401 | 53.181 | 47.108 | 1.00 | 13.40 | E | C |
| ATOM | 9582 | OG | SER | E | 647 | −13.025 | 53.379 | 47.344 | 1.00 | 20.55 | E | O |
| ATOM | 9583 | C | SER | E | 647 | −15.278 | 54.844 | 48.760 | 1.00 | 14.49 | E | C |
| ATOM | 9584 | O | SER | E | 647 | −14.600 | 55.748 | 49.239 | 1.00 | 15.50 | E | O |
| ATOM | 9585 | N | THR | E | 648 | −16.118 | 54.102 | 49.464 | 1.00 | 15.98 | E | N |
| ATOM | 9586 | CA | THR | E | 648 | −16.417 | 54.309 | 50.877 | 1.00 | 15.80 | E | C |
| ATOM | 9587 | CB | THR | E | 648 | −17.906 | 53.932 | 51.113 | 1.00 | 14.90 | E | C |
| ATOM | 9588 | OG1 | THR | E | 648 | −18.493 | 54.840 | 52.046 | 1.00 | 25.25 | E | O |
| ATOM | 9589 | CG2 | THR | E | 648 | −18.031 | 52.521 | 51.607 | 1.00 | 7.44 | E | C |
| ATOM | 9590 | C | THR | E | 648 | −15.524 | 53.584 | 51.895 | 1.00 | 14.14 | E | C |
| ATOM | 9591 | O | THR | E | 648 | −15.245 | 54.122 | 52.970 | 1.00 | 12.98 | E | O |
| ATOM | 9592 | N | ASP | E | 649 | −15.081 | 52.377 | 51.545 | 1.00 | 14.78 | E | N |
| ATOM | 9593 | CA | ASP | E | 649 | −14.239 | 51.531 | 52.402 | 1.00 | 12.95 | E | C |
| ATOM | 9594 | CB | ASP | E | 649 | −13.015 | 52.293 | 52.913 | 1.00 | 12.22 | E | C |
| ATOM | 9595 | CG | ASP | E | 649 | −11.874 | 51.365 | 53.290 | 1.00 | 12.29 | E | C |
| ATOM | 9596 | OD1 | ASP | E | 649 | −12.013 | 50.137 | 53.093 | 1.00 | 14.60 | E | O |
| ATOM | 9597 | OD2 | ASP | E | 649 | −10.837 | 51.865 | 53.779 | 1.00 | 13.25 | E | O |
| ATOM | 9598 | C | ASP | E | 649 | −14.981 | 50.915 | 53.589 | 1.00 | 14.90 | E | C |
| ATOM | 9599 | O | ASP | E | 649 | −15.272 | 49.723 | 53.573 | 1.00 | 14.03 | E | O |
| ATOM | 9600 | N | ASP | E | 650 | −15.278 | 51.720 | 54.613 | 1.00 | 17.27 | E | N |
| ATOM | 9601 | CA | ASP | E | 650 | −15.995 | 51.250 | 55.805 | 1.00 | 16.84 | E | C |
| ATOM | 9602 | CB | ASP | E | 650 | −15.006 | 50.906 | 56.920 | 1.00 | 16.99 | E | C |
| ATOM | 9603 | CG | ASP | E | 650 | −14.150 | 49.691 | 56.593 | 1.00 | 22.35 | E | C |
| ATOM | 9604 | OD1 | ASP | E | 650 | −12.943 | 49.857 | 56.331 | 1.00 | 28.30 | E | O |
| ATOM | 9605 | OD2 | ASP | E | 650 | −14.672 | 48.558 | 56.603 | 1.00 | 26.19 | E | O |
| ATOM | 9606 | C | ASP | E | 650 | −16.968 | 52.325 | 56.303 | 1.00 | 16.55 | E | C |
| ATOM | 9607 | O | ASP | E | 650 | −16.662 | 53.068 | 57.228 | 1.00 | 12.53 | E | O |
| ATOM | 9608 | N | PRO | E | 651 | −18.162 | 52.408 | 55.695 | 1.00 | 16.64 | E | N |
| ATOM | 9609 | CD | PRO | E | 651 | −18.639 | 51.549 | 54.597 | 1.00 | 16.85 | E | C |
| ATOM | 9610 | CA | PRO | E | 651 | −19.161 | 53.402 | 56.089 | 1.00 | 16.60 | E | C |
| ATOM | 9611 | CB | PRO | E | 651 | −20.415 | 52.993 | 55.321 | 1.00 | 18.08 | E | C |
| ATOM | 9612 | CG | PRO | E | 651 | −19.925 | 52.195 | 54.180 | 1.00 | 17.01 | E | C |
| ATOM | 9613 | C | PRO | E | 651 | −19.416 | 53.472 | 57.580 | 1.00 | 17.19 | E | C |
| ATOM | 9614 | O | PRO | E | 651 | −19.483 | 54.562 | 58.148 | 1.00 | 16.99 | E | O |
| ATOM | 9615 | N | MET | E | 652 | −19.559 | 52.308 | 58.207 | 1.00 | 18.19 | E | N |
| ATOM | 9616 | CA | MET | E | 652 | −19.819 | 52.230 | 59.643 | 1.00 | 18.83 | E | C |
| ATOM | 9617 | CB | MET | E | 652 | −19.817 | 50.775 | 60.099 | 1.00 | 20.21 | E | C |
| ATOM | 9618 | CG | MET | E | 652 | −20.157 | 50.595 | 61.567 | 1.00 | 21.69 | E | C |
| ATOM | 9619 | SD | MET | E | 652 | −20.348 | 48.877 | 62.011 | 1.00 | 28.37 | E | S |
| ATOM | 9620 | CE | MET | E | 652 | −18.637 | 48.350 | 62.115 | 1.00 | 21.38 | E | C |
| ATOM | 9621 | C | MET | E | 652 | −18.814 | 53.012 | 60.475 | 1.00 | 18.01 | E | C |
| ATOM | 9622 | O | MET | E | 652 | −19.174 | 53.646 | 61.462 | 1.00 | 18.35 | E | O |
| ATOM | 9623 | N | GLN | E | 653 | −17.555 | 52.970 | 60.057 | 1.00 | 18.60 | E | N |
| ATOM | 9624 | CA | GLN | E | 653 | −16.469 | 53.649 | 60.750 | 1.00 | 18.80 | E | C |
| ATOM | 9625 | CB | GLN | E | 653 | −15.158 | 52.900 | 60.495 | 1.00 | 21.05 | E | C |
| ATOM | 9626 | CG | GLN | E | 653 | −14.655 | 52.052 | 61.634 | 1.00 | 27.69 | E | C |
| ATOM | 9627 | CD | GLN | E | 653 | −15.125 | 50.627 | 61.516 | 1.00 | 35.27 | E | C |
| ATOM | 9628 | OE1 | GLN | E | 653 | −16.045 | 50.205 | 62.214 | 1.00 | 41.52 | E | O |
| ATOM | 9629 | NE2 | GLN | E | 653 | −14.501 | 49.872 | 60.625 | 1.00 | 39.02 | E | N |
| ATOM | 9630 | C | GLN | E | 653 | −16.240 | 55.121 | 60.371 | 1.00 | 18.83 | E | C |
| ATOM | 9631 | O | GLN | E | 653 | −15.849 | 55.923 | 61.220 | 1.00 | 15.21 | E | O |
| ATOM | 9632 | N | PHE | E | 654 | −16.486 | 55.484 | 59.113 | 1.00 | 18.45 | E | N |
| ATOM | 9633 | CA | PHE | E | 654 | −16.186 | 56.845 | 58.676 | 1.00 | 17.32 | E | C |
| ATOM | 9634 | CB | PHE | E | 654 | −15.156 | 56.796 | 57.538 | 1.00 | 17.58 | E | C |
| ATOM | 9635 | CG | PHE | E | 654 | −14.050 | 55.787 | 57.740 | 1.00 | 16.25 | E | C |
| ATOM | 9636 | CD1 | PHE | E | 654 | −13.969 | 54.663 | 56.931 | 1.00 | 14.09 | E | C |
| ATOM | 9637 | CD2 | PHE | E | 654 | −13.056 | 55.994 | 58.701 | 1.00 | 14.85 | E | C |
| ATOM | 9638 | CE1 | PHE | E | 654 | −12.911 | 53.752 | 57.065 | 1.00 | 15.71 | E | C |
| ATOM | 9639 | CE2 | PHE | E | 654 | −11.995 | 55.091 | 58.845 | 1.00 | 14.71 | E | C |
| ATOM | 9640 | CZ | PHE | E | 654 | −11.924 | 53.968 | 58.022 | 1.00 | 15.24 | E | C |
| ATOM | 9641 | C | PHE | E | 654 | −17.284 | 57.801 | 58.235 | 1.00 | 18.77 | E | C |
| ATOM | 9642 | O | PHE | E | 654 | −17.013 | 58.996 | 58.081 | 1.00 | 19.89 | E | O |
| ATOM | 9643 | N | HIS | E | 655 | −18.505 | 57.320 | 58.030 | 1.00 | 18.24 | E | N |
| ATOM | 9644 | CA | HIS | E | 655 | −19.554 | 58.211 | 57.543 | 1.00 | 20.62 | E | C |
| ATOM | 9645 | CB | HIS | E | 655 | −20.134 | 57.616 | 56.254 | 1.00 | 19.03 | E | C |
| ATOM | 9646 | CG | HIS | E | 655 | −19.078 | 57.257 | 55.247 | 1.00 | 20.16 | E | C |
| ATOM | 9647 | CD2 | HIS | E | 655 | −18.337 | 56.134 | 55.097 | 1.00 | 17.23 | E | C |
| ATOM | 9648 | ND1 | HIS | E | 655 | −18.596 | 58.157 | 54.320 | 1.00 | 19.72 | E | N |
| ATOM | 9649 | CE1 | HIS | E | 655 | −17.601 | 57.606 | 53.648 | 1.00 | 18.31 | E | C |
| ATOM | 9650 | NE2 | HIS | E | 655 | −17.423 | 56.376 | 54.102 | 1.00 | 15.43 | E | N |
| ATOM | 9651 | C | HIS | E | 655 | −20.655 | 58.577 | 58.535 | 1.00 | 21.71 | E | C |
| ATOM | 9652 | O | HIS | E | 655 | −20.977 | 57.798 | 59.428 | 1.00 | 23.93 | E | O |
| ATOM | 9653 | N | PHE | E | 656 | −21.220 | 59.774 | 58.362 | 1.00 | 23.87 | E | N |
| ATOM | 9654 | CA | PHE | E | 656 | −22.265 | 60.311 | 59.235 | 1.00 | 25.20 | E | C |
| ATOM | 9655 | CB | PHE | E | 656 | −21.979 | 61.781 | 59.554 | 1.00 | 23.28 | E | C |
| ATOM | 9656 | CG | PHE | E | 656 | −20.729 | 62.006 | 60.354 | 1.00 | 22.14 | E | C |
| ATOM | 9657 | CD1 | PHE | E | 656 | −19.569 | 62.441 | 59.737 | 1.00 | 24.08 | E | C |
| ATOM | 9658 | CD2 | PHE | E | 656 | −20.715 | 61.803 | 61.729 | 1.00 | 27.22 | E | C |
| ATOM | 9659 | CE1 | PHE | E | 656 | −18.411 | 62.673 | 60.471 | 1.00 | 24.60 | E | C |
| ATOM | 9660 | CE2 | PHE | E | 656 | −19.562 | 62.032 | 62.475 | 1.00 | 25.59 | E | C |
| ATOM | 9661 | CZ | PHE | E | 656 | −18.408 | 62.469 | 61.841 | 1.00 | 26.42 | E | C |
| ATOM | 9662 | C | PHE | E | 656 | −23.696 | 60.234 | 58.715 | 1.00 | 27.97 | E | C |
| ATOM | 9663 | O | PHE | E | 656 | −24.641 | 60.261 | 59.510 | 1.00 | 32.67 | E | O |
| ATOM | 9664 | N | THR | E | 657 | −23.866 | 60.149 | 57.398 | 1.00 | 29.04 | E | N |
| ATOM | 9665 | CA | THR | E | 657 | −25.202 | 60.124 | 56.792 | 1.00 | 28.85 | E | C |
| ATOM | 9666 | CB | THR | E | 657 | −25.247 | 61.000 | 55.536 | 1.00 | 28.75 | E | C |
| ATOM | 9667 | OG1 | THR | E | 657 | −24.835 | 60.223 | 54.406 | 1.00 | 30.75 | E | O |
| ATOM | 9668 | CG2 | THR | E | 657 | −24.311 | 62.188 | 55.675 | 1.00 | 24.54 | E | C |
| ATOM | 9669 | C | THR | E | 657 | −25.670 | 58.740 | 56.388 | 1.00 | 32.57 | E | C |
| ATOM | 9670 | O | THR | E | 657 | −24.958 | 57.752 | 56.600 | 1.00 | 33.80 | E | O |
| ATOM | 9671 | N | LYS | E | 658 | −26.866 | 58.680 | 55.791 | 1.00 | 33.62 | E | N |
| ATOM | 9672 | CA | LYS | E | 658 | −27.457 | 57.415 | 55.341 | 1.00 | 36.01 | E | C |
| ATOM | 9673 | CB | LYS | E | 658 | −28.991 | 57.475 | 55.412 | 1.00 | 40.29 | E | C |
| ATOM | 9674 | CG | LYS | E | 658 | −29.590 | 57.264 | 56.809 | 1.00 | 45.84 | E | C |
| ATOM | 9675 | CD | LYS | E | 658 | −29.919 | 55.788 | 57.093 | 1.00 | 47.85 | E | C |
| ATOM | 9676 | CE | LYS | E | 658 | −30.151 | 55.542 | 58.593 | 1.00 | 45.16 | E | C |
| ATOM | 9677 | NZ | LYS | E | 658 | −29.081 | 54.711 | 59.206 | 1.00 | 40.38 | E | N |
| ATOM | 9678 | C | LYS | E | 658 | −27.048 | 57.085 | 53.908 | 1.00 | 35.27 | E | C |
| ATOM | 9679 | O | LYS | E | 658 | −27.358 | 56.001 | 53.397 | 1.00 | 37.35 | E | O |
| ATOM | 9680 | N | GLU | E | 659 | −26.374 | 58.027 | 53.253 | 1.00 | 32.65 | E | N |
| ATOM | 9681 | CA | GLU | E | 659 | −25.916 | 57.822 | 51.879 | 1.00 | 32.55 | E | C |
| ATOM | 9682 | CB | GLU | E | 659 | −26.674 | 58.758 | 50.928 | 1.00 | 34.95 | E | C |
| ATOM | 9683 | CG | GLU | E | 659 | −28.108 | 58.301 | 50.646 | 1.00 | 38.98 | E | C |
| ATOM | 9684 | CD | GLU | E | 659 | −28.735 | 58.990 | 49.438 | 1.00 | 42.99 | E | C |
| ATOM | 9685 | OE1 | GLU | E | 659 | −28.675 | 58.417 | 48.322 | 1.00 | 42.71 | E | O |
| ATOM | 9686 | OE2 | GLU | E | 659 | −29.291 | 60.102 | 49.608 | 1.00 | 44.77 | E | O |
| ATOM | 9687 | C | GLU | E | 659 | −24.408 | 58.083 | 51.821 | 1.00 | 29.04 | E | C |
| ATOM | 9688 | O | GLU | E | 659 | −23.947 | 59.084 | 51.257 | 1.00 | 27.27 | E | O |
| ATOM | 9689 | N | PRO | E | 660 | −23.621 | 57.179 | 52.432 | 1.00 | 27.20 | E | N |
| ATOM | 9690 | CD | PRO | E | 660 | −24.115 | 56.001 | 53.168 | 1.00 | 23.78 | E | C |
| ATOM | 9691 | CA | PRO | E | 660 | −22.158 | 57.295 | 52.470 | 1.00 | 24.39 | E | C |
| ATOM | 9692 | CB | PRO | E | 660 | −21.691 | 56.002 | 53.148 | 1.00 | 24.51 | E | C |
| ATOM | 9693 | CG | PRO | E | 660 | −22.908 | 55.144 | 53.300 | 1.00 | 25.65 | E | C |
| ATOM | 9694 | C | PRO | E | 660 | −21.477 | 57.525 | 51.130 | 1.00 | 21.45 | E | C |
| ATOM | 9695 | O | PRO | E | 660 | −20.545 | 58.331 | 51.047 | 1.00 | 24.07 | E | O |
| ATOM | 9696 | N | LEU | E | 661 | −21.911 | 56.831 | 50.082 | 1.00 | 19.25 | E | N |
| ATOM | 9697 | CA | LEU | E | 661 | −21.288 | 57.029 | 48.766 | 1.00 | 16.86 | E | C |
| ATOM | 9698 | CB | LEU | E | 661 | −21.876 | 56.077 | 47.722 | 1.00 | 13.95 | E | C |
| ATOM | 9699 | CG | LEU | E | 661 | −20.927 | 55.401 | 46.707 | 1.00 | 15.58 | E | C |
| ATOM | 9700 | CD1 | LEU | E | 661 | −21.554 | 55.452 | 45.320 | 1.00 | 11.17 | E | C |
| ATOM | 9701 | CD2 | LEU | E | 661 | −19.558 | 56.065 | 46.683 | 1.00 | 8.02 | E | C |
| ATOM | 9702 | C | LEU | E | 661 | −21.498 | 58.476 | 48.325 | 1.00 | 15.27 | E | C |
| ATOM | 9703 | O | LEU | E | 661 | −20.564 | 59.131 | 47.871 | 1.00 | 16.34 | E | O |
| ATOM | 9704 | N | MET | E | 662 | −22.725 | 58.968 | 48.468 | 1.00 | 14.82 | E | N |
| ATOM | 9705 | CA | MET | E | 662 | −23.056 | 60.343 | 48.110 | 1.00 | 15.90 | E | C |
| ATOM | 9706 | CB | MET | E | 662 | −24.554 | 60.602 | 48.279 | 1.00 | 17.07 | E | C |
| ATOM | 9707 | CG | MET | E | 662 | −25.432 | 59.758 | 47.360 | 1.00 | 25.57 | E | C |
| ATOM | 9708 | SD | MET | E | 662 | −25.021 | 59.947 | 45.581 | 1.00 | 33.09 | E | S |
| ATOM | 9709 | CE | MET | E | 662 | −25.193 | 61.772 | 45.400 | 1.00 | 28.64 | E | C |
| ATOM | 9710 | C | MET | E | 662 | −22.275 | 61.289 | 49.008 | 1.00 | 17.19 | E | C |
| ATOM | 9711 | O | MET | E | 662 | −21.925 | 62.400 | 48.599 | 1.00 | 18.25 | E | O |
| ATOM | 9712 | N | GLU | E | 663 | −22.004 | 60.847 | 50.233 | 1.00 | 13.97 | E | N |
| ATOM | 9713 | CA | GLU | E | 663 | −21.246 | 61.653 | 51.184 | 1.00 | 13.15 | E | C |
| ATOM | 9714 | CB | GLU | E | 663 | −21.280 | 60.999 | 52.565 | 1.00 | 16.87 | E | C |
| ATOM | 9715 | CG | GLU | E | 663 | −21.017 | 61.947 | 53.721 | 1.00 | 19.20 | E | C |
| ATOM | 9716 | CD | GLU | E | 663 | −20.997 | 61.234 | 55.060 | 1.00 | 19.47 | E | C |
| ATOM | 9717 | OE1 | GLU | E | 663 | −21.854 | 60.344 | 55.260 | 1.00 | 16.21 | E | O |
| ATOM | 9718 | OE2 | GLU | E | 663 | −20.129 | 61.563 | 55.899 | 1.00 | 15.08 | E | O |
| ATOM | 9719 | C | GLU | E | 663 | −19.798 | 61.806 | 50.707 | 1.00 | 12.36 | E | C |
| ATOM | 9720 | O | GLU | E | 663 | −19.241 | 62.902 | 50.767 | 1.00 | 9.15 | E | O |
| ATOM | 9721 | N | GLU | E | 664 | −19.194 | 60.712 | 50.233 | 1.00 | 9.68 | E | N |
| ATOM | 9722 | CA | GLU | E | 664 | −17.816 | 60.759 | 49.745 | 1.00 | 11.87 | E | C |
| ATOM | 9723 | CB | GLU | E | 664 | −17.309 | 59.358 | 49.394 | 1.00 | 12.99 | E | C |
| ATOM | 9724 | CG | GLU | E | 664 | −16.907 | 58.526 | 50.601 | 1.00 | 21.43 | E | C |
| ATOM | 9725 | CD | GLU | E | 664 | −15.418 | 58.554 | 50.890 | 1.00 | 17.81 | E | C |
| ATOM | 9726 | OE1 | GLU | E | 664 | −14.687 | 59.343 | 50.250 | 1.00 | 20.63 | E | O |
| ATOM | 9727 | OE2 | GLU | E | 664 | −14.980 | 57.783 | 51.769 | 1.00 | 24.13 | E | O |
| ATOM | 9728 | C | GLU | E | 664 | −17.699 | 61.654 | 48.517 | 1.00 | 10.43 | E | C |
| ATOM | 9729 | O | GLU | E | 664 | −16.740 | 62.414 | 48.382 | 1.00 | 12.29 | E | O |
| ATOM | 9730 | N | TYR | E | 665 | −18.682 | 61.560 | 47.629 | 1.00 | 10.29 | E | N |
| ATOM | 9731 | CA | TYR | E | 665 | −18.701 | 62.363 | 46.416 | 1.00 | 11.18 | E | C |
| ATOM | 9732 | CB | TYR | E | 665 | −19.834 | 61.905 | 45.488 | 1.00 | 10.35 | E | C |
| ATOM | 9733 | CG | TYR | E | 665 | −19.443 | 60.820 | 44.501 | 1.00 | 11.53 | E | C |
| ATOM | 9734 | CD1 | TYR | E | 665 | −19.450 | 59.477 | 44.870 | 1.00 | 10.80 | E | C |
| ATOM | 9735 | CE1 | TYR | E | 665 | −19.117 | 58.474 | 43.959 | 1.00 | 9.15 | E | C |
| ATOM | 9736 | CD2 | TYR | E | 665 | −19.087 | 61.136 | 43.185 | 1.00 | 16.01 | E | C |
| ATOM | 9737 | CE2 | TYR | E | 665 | −18.749 | 60.134 | 42.257 | 1.00 | 11.91 | E | C |
| ATOM | 9738 | CZ | TYR | E | 665 | −18.770 | 58.811 | 42.657 | 1.00 | 12.87 | E | C |
| ATOM | 9739 | OH | TYR | E | 665 | −18.455 | 57.825 | 41.754 | 1.00 | 15.88 | E | O |
| ATOM | 9740 | C | TYR | E | 665 | −18.881 | 63.832 | 46.750 | 1.00 | 9.13 | E | C |
| ATOM | 9741 | O | TYR | E | 665 | −18.179 | 64.683 | 46.212 | 1.00 | 14.60 | E | O |
| ATOM | 9742 | N | ALA | E | 666 | −19.820 | 64.132 | 47.641 | 1.00 | 8.92 | E | N |
| ATOM | 9743 | CA | ALA | E | 666 | −20.091 | 65.518 | 48.046 | 1.00 | 8.83 | E | C |
| ATOM | 9744 | CB | ALA | E | 666 | −21.257 | 65.559 | 49.011 | 1.00 | 6.45 | E | C |
| ATOM | 9745 | C | ALA | E | 666 | −18.902 | 66.237 | 48.659 | 1.00 | 7.40 | E | C |
| ATOM | 9746 | O | ALA | E | 666 | −18.568 | 67.339 | 48.250 | 1.00 | 8.64 | E | O |
| ATOM | 9747 | N | ILE | E | 667 | −18.262 | 65.624 | 49.644 | 1.00 | 10.47 | E | N |
| ATOM | 9748 | CA | ILE | E | 667 | −17.125 | 66.273 | 50.283 | 1.00 | 14.24 | E | C |
| ATOM | 9749 | CB | ILE | E | 667 | −16.625 | 65.482 | 51.524 | 1.00 | 14.70 | E | C |
| ATOM | 9750 | CG2 | ILE | E | 667 | −16.277 | 64.054 | 51.131 | 1.00 | 18.37 | E | C |
| ATOM | 9751 | CG1 | ILE | E | 667 | −15.406 | 66.188 | 52.125 | 1.00 | 17.24 | E | C |
| ATOM | 9752 | CD1 | ILE | E | 667 | −14.814 | 65.488 | 53.323 | 1.00 | 21.32 | E | C |
| ATOM | 9753 | C | ILE | E | 667 | −15.985 | 66.438 | 49.287 | 1.00 | 14.50 | E | C |
| ATOM | 9754 | O | ILE | E | 667 | −15.310 | 67.469 | 49.267 | 1.00 | 13.96 | E | O |
| ATOM | 9755 | N | ALA | E | 668 | −15.766 | 65.425 | 48.456 | 1.00 | 12.72 | E | N |
| ATOM | 9756 | CA | ALA | E | 668 | −14.702 | 65.518 | 47.467 | 1.00 | 11.08 | E | C |
| ATOM | 9757 | CB | ALA | E | 668 | −14.623 | 64.230 | 46.648 | 1.00 | 10.14 | E | C |
| ATOM | 9758 | C | ALA | E | 668 | −14.977 | 66.712 | 46.557 | 1.00 | 7.61 | E | C |
| ATOM | 9759 | O | ALA | E | 668 | −14.078 | 67.484 | 46.260 | 1.00 | 10.15 | E | O |
| ATOM | 9760 | N | ALA | E | 669 | −16.224 | 66.868 | 46.131 | 1.00 | 5.01 | E | N |
| ATOM | 9761 | CA | ALA | E | 669 | −16.602 | 67.982 | 45.257 | 1.00 | 10.05 | E | C |
| ATOM | 9762 | CB | ALA | E | 669 | −18.047 | 67.814 | 44.773 | 1.00 | 2.28 | E | C |
| ATOM | 9763 | C | ALA | E | 669 | −16.447 | 69.328 | 45.955 | 1.00 | 10.20 | E | C |
| ATOM | 9764 | O | ALA | E | 669 | −15.981 | 70.292 | 45.355 | 1.00 | 10.19 | E | O |
| ATOM | 9765 | N | GLN | E | 670 | −16.840 | 69.385 | 47.225 | 1.00 | 13.63 | E | N |
| ATOM | 9766 | CA | GLN | E | 670 | −16.746 | 70.610 | 48.010 | 1.00 | 15.09 | E | C |
| ATOM | 9767 | CB | GLN | E | 670 | −17.422 | 70.431 | 49.377 | 1.00 | 20.31 | E | C |
| ATOM | 9768 | CG | GLN | E | 670 | −18.841 | 69.869 | 49.333 | 1.00 | 21.97 | E | C |
| ATOM | 9769 | CD | GLN | E | 670 | −19.895 | 70.945 | 49.162 | 1.00 | 25.98 | E | C |
| ATOM | 9770 | OE1 | GLN | E | 670 | −19.600 | 72.049 | 48.700 | 1.00 | 27.58 | E | O |
| ATOM | 9771 | NE2 | GLN | E | 670 | −21.135 | 70.629 | 49.533 | 1.00 | 24.40 | E | N |
| ATOM | 9772 | C | GLN | E | 670 | −15.310 | 71.091 | 48.220 | 1.00 | 15.21 | E | C |
| ATOM | 9773 | O | GLN | E | 670 | −14.978 | 72.216 | 47.848 | 1.00 | 17.63 | E | O |
| ATOM | 9774 | N | VAL | E | 671 | −14.450 | 70.260 | 48.803 | 1.00 | 14.12 | E | N |
| ATOM | 9775 | CA | VAL | E | 671 | −13.078 | 70.707 | 49.033 | 1.00 | 15.10 | E | C |
| ATOM | 9776 | CB | VAL | E | 671 | −12.406 | 69.962 | 50.251 | 1.00 | 12.13 | E | C |
| ATOM | 9777 | CG1 | VAL | E | 671 | −13.413 | 69.105 | 50.967 | 1.00 | 9.55 | E | C |
| ATOM | 9778 | CG2 | VAL | E | 671 | −11.221 | 69.144 | 49.798 | 1.00 | 9.55 | E | C |
| ATOM | 9779 | C | VAL | E | 671 | −12.158 | 70.659 | 47.807 | 1.00 | 14.16 | E | C |
| ATOM | 9780 | O | VAL | E | 671 | −11.248 | 71.476 | 47.691 | 1.00 | 16.69 | E | O |
| ATOM | 9781 | N | PHE | E | 672 | −12.379 | 69.731 | 46.887 | 1.00 | 13.12 | E | N |
| ATOM | 9782 | CA | PHE | E | 672 | −11.522 | 69.670 | 45.707 | 1.00 | 14.92 | E | C |
| ATOM | 9783 | CB | PHE | E | 672 | −11.323 | 68.221 | 45.278 | 1.00 | 12.48 | E | C |
| ATOM | 9784 | CG | PHE | E | 672 | −10.444 | 67.445 | 46.217 | 1.00 | 18.14 | E | C |
| ATOM | 9785 | CD1 | PHE | E | 672 | −9.130 | 67.852 | 46.455 | 1.00 | 17.62 | E | C |
| ATOM | 9786 | CD2 | PHE | E | 672 | −10.934 | 66.342 | 46.900 | 1.00 | 14.94 | E | C |
| ATOM | 9787 | CE1 | PHE | E | 672 | −8.324 | 67.169 | 47.364 | 1.00 | 17.50 | E | C |
| ATOM | 9788 | CE2 | PHE | E | 672 | −10.135 | 65.655 | 47.810 | 1.00 | 14.80 | E | C |
| ATOM | 9789 | CZ | PHE | E | 672 | −8.830 | 66.069 | 48.043 | 1.00 | 17.53 | E | C |
| ATOM | 9790 | C | PHE | E | 672 | −12.056 | 70.507 | 44.551 | 1.00 | 15.06 | E | C |
| ATOM | 9791 | O | PHE | E | 672 | −11.446 | 70.573 | 43.496 | 1.00 | 15.95 | E | O |
| ATOM | 9792 | N | LYS | E | 673 | −13.197 | 71.152 | 44.780 | 1.00 | 18.40 | E | N |
| ATOM | 9793 | CA | LYS | E | 673 | −13.851 | 72.020 | 43.806 | 1.00 | 17.62 | E | C |
| ATOM | 9794 | CB | LYS | E | 673 | −13.051 | 73.316 | 43.642 | 1.00 | 17.15 | E | C |
| ATOM | 9795 | CG | LYS | E | 673 | −13.621 | 74.469 | 44.458 | 1.00 | 19.79 | E | C |
| ATOM | 9796 | CD | LYS | E | 673 | −12.547 | 75.309 | 45.146 | 1.00 | 30.20 | E | C |
| ATOM | 9797 | CE | LYS | E | 673 | −11.234 | 74.535 | 45.365 | 1.00 | 38.53 | E | C |
| ATOM | 9798 | NZ | LYS | E | 673 | −10.152 | 75.339 | 46.041 | 1.00 | 39.11 | E | N |
| ATOM | 9799 | C | LYS | E | 673 | −14.073 | 71.360 | 42.455 | 1.00 | 18.50 | E | C |
| ATOM | 9800 | O | LYS | E | 673 | −13.728 | 71.913 | 41.410 | 1.00 | 21.08 | E | O |
| ATOM | 9801 | N | LEU | E | 674 | −14.673 | 70.178 | 42.491 | 1.00 | 17.44 | E | N |
| ATOM | 9802 | CA | LEU | E | 674 | −14.971 | 69.402 | 41.292 | 1.00 | 16.77 | E | C |
| ATOM | 9803 | CB | LEU | E | 674 | −15.234 | 67.937 | 41.669 | 1.00 | 14.87 | E | C |
| ATOM | 9804 | CG | LEU | E | 674 | −14.091 | 66.925 | 41.737 | 1.00 | 10.38 | E | C |
| ATOM | 9805 | CD1 | LEU | E | 674 | −12.760 | 67.616 | 41.878 | 1.00 | 11.23 | E | C |
| ATOM | 9806 | CD2 | LEU | E | 674 | −14.339 | 66.007 | 42.900 | 1.00 | 9.75 | E | C |
| ATOM | 9807 | C | LEU | E | 674 | −16.200 | 69.942 | 40.565 | 1.00 | 15.37 | E | C |
| ATOM | 9808 | O | LEU | E | 674 | −17.162 | 70.357 | 41.193 | 1.00 | 12.74 | E | O |
| ATOM | 9809 | N | SER | E | 675 | −16.159 | 69.923 | 39.237 | 1.00 | 16.67 | E | N |
| ATOM | 9810 | CA | SER | E | 675 | −17.283 | 70.378 | 38.420 | 1.00 | 15.27 | E | C |
| ATOM | 9811 | CB | SER | E | 675 | −16.802 | 70.775 | 37.026 | 1.00 | 14.65 | E | C |
| ATOM | 9812 | OG | SER | E | 675 | −16.430 | 69.620 | 36.290 | 1.00 | 16.84 | E | O |
| ATOM | 9813 | C | SER | E | 675 | −18.215 | 69.185 | 38.297 | 1.00 | 15.36 | E | C |
| ATOM | 9814 | O | SER | E | 675 | −17.824 | 68.055 | 38.608 | 1.00 | 16.16 | E | O |
| ATOM | 9815 | N | THR | E | 676 | −19.441 | 69.411 | 37.842 | 1.00 | 16.38 | E | N |
| ATOM | 9816 | CA | THR | E | 676 | −20.364 | 68.297 | 37.703 | 1.00 | 15.66 | E | C |
| ATOM | 9817 | CB | THR | E | 676 | −21.822 | 68.778 | 37.479 | 1.00 | 16.79 | E | C |
| ATOM | 9818 | OG1 | THR | E | 676 | −22.385 | 68.101 | 36.350 | 1.00 | 26.81 | E | O |
| ATOM | 9819 | CG2 | THR | E | 676 | −21.868 | 70.268 | 37.254 | 1.00 | 21.71 | E | C |
| ATOM | 9820 | C | THR | E | 676 | −19.896 | 67.374 | 36.573 | 1.00 | 14.98 | E | C |
| ATOM | 9821 | O | THR | E | 676 | −20.273 | 66.207 | 36.521 | 1.00 | 15.94 | E | O |
| ATOM | 9822 | N | CYS | E | 677 | −19.046 | 67.877 | 35.682 | 1.00 | 14.10 | E | N |
| ATOM | 9823 | CA | CYS | E | 677 | −18.531 | 67.024 | 34.616 | 1.00 | 12.43 | E | C |
| ATOM | 9824 | CB | CYS | E | 677 | −17.904 | 67.848 | 33.487 | 1.00 | 14.25 | E | C |
| ATOM | 9825 | SG | CYS | E | 677 | −17.349 | 66.841 | 32.063 | 1.00 | 15.32 | E | S |
| ATOM | 9826 | C | CYS | E | 677 | −17.469 | 66.130 | 35.240 | 1.00 | 12.75 | E | C |
| ATOM | 9827 | O | CYS | E | 677 | −17.359 | 64.956 | 34.893 | 1.00 | 14.24 | E | O |
| ATOM | 9828 | N | ASP | E | 678 | −16.682 | 66.701 | 36.153 | 1.00 | 13.17 | E | N |
| ATOM | 9829 | CA | ASP | E | 678 | −15.633 | 65.965 | 36.862 | 1.00 | 12.82 | E | C |
| ATOM | 9830 | CB | ASP | E | 678 | −14.896 | 66.883 | 37.837 | 1.00 | 14.28 | E | C |
| ATOM | 9831 | CG | ASP | E | 678 | −14.066 | 67.933 | 37.144 | 1.00 | 14.91 | E | C |
| ATOM | 9832 | OD1 | ASP | E | 678 | −13.596 | 67.678 | 36.015 | 1.00 | 19.66 | E | O |
| ATOM | 9833 | OD2 | ASP | E | 678 | −13.878 | 69.018 | 37.732 | 1.00 | 14.14 | E | O |
| ATOM | 9834 | C | ASP | E | 678 | −16.257 | 64.834 | 37.668 | 1.00 | 13.39 | E | C |
| ATOM | 9835 | O | ASP | E | 678 | −15.736 | 63.722 | 37.703 | 1.00 | 13.56 | E | O |
| ATOM | 9836 | N | MET | E | 679 | −17.378 | 65.134 | 38.316 | 1.00 | 12.07 | E | N |
| ATOM | 9837 | CA | MET | E | 679 | −18.079 | 64.159 | 39.140 | 1.00 | 13.16 | E | C |
| ATOM | 9838 | CB | MET | E | 679 | −19.225 | 64.834 | 39.894 | 1.00 | 14.20 | E | C |
| ATOM | 9839 | CG | MET | E | 679 | −18.791 | 65.866 | 40.903 | 1.00 | 18.44 | E | C |
| ATOM | 9840 | SD | MET | E | 679 | −20.144 | 66.305 | 42.004 | 1.00 | 27.83 | E | S |
| ATOM | 9841 | CE | MET | E | 679 | −20.764 | 67.760 | 41.226 | 1.00 | 26.90 | E | C |
| ATOM | 9842 | C | MET | E | 679 | −18.647 | 63.021 | 38.317 | 1.00 | 12.95 | E | C |
| ATOM | 9843 | O | MET | E | 679 | −18.576 | 61.854 | 38.705 | 1.00 | 13.09 | E | O |
| ATOM | 9844 | N | CYS | E | 680 | −19.235 | 63.364 | 37.181 | 1.00 | 13.38 | E | N |
| ATOM | 9845 | CA | CYS | E | 680 | −19.824 | 62.352 | 36.324 | 1.00 | 14.76 | E | C |
| ATOM | 9846 | CB | CYS | E | 680 | −20.705 | 63.009 | 35.270 | 1.00 | 16.87 | E | C |
| ATOM | 9847 | SG | CYS | E | 680 | −22.207 | 63.740 | 35.969 | 1.00 | 21.04 | E | S |
| ATOM | 9848 | C | CYS | E | 680 | −18.751 | 61.500 | 35.675 | 1.00 | 13.98 | E | C |
| ATOM | 9849 | O | CYS | E | 680 | −19.002 | 60.347 | 35.330 | 1.00 | 17.83 | E | O |
| ATOM | 9850 | N | GLU | E | 681 | −17.554 | 62.051 | 35.507 | 1.00 | 11.94 | E | N |
| ATOM | 9851 | CA | GLU | E | 681 | −16.475 | 61.269 | 34.913 | 1.00 | 12.51 | E | C |
| ATOM | 9852 | CB | GLU | E | 681 | −15.278 | 62.155 | 34.521 | 1.00 | 9.85 | E | C |
| ATOM | 9853 | CG | GLU | E | 681 | −14.139 | 61.361 | 33.899 | 1.00 | 14.97 | E | C |
| ATOM | 9854 | CD | GLU | E | 681 | −12.965 | 62.216 | 33.411 | 1.00 | 18.17 | E | C |
| ATOM | 9855 | OE1 | GLU | E | 681 | −12.746 | 63.324 | 33.946 | 1.00 | 17.02 | E | O |
| ATOM | 9856 | OE2 | GLU | E | 681 | −12.253 | 61.762 | 32.485 | 1.00 | 20.53 | E | O |
| ATOM | 9857 | C | GLU | E | 681 | −16.040 | 60.224 | 35.931 | 1.00 | 11.86 | E | C |
| ATOM | 9858 | O | GLU | E | 681 | −15.723 | 59.095 | 35.571 | 1.00 | 16.44 | E | O |
| ATOM | 9859 | N | VAL | E | 682 | −16.025 | 60.590 | 37.209 | 1.00 | 10.08 | E | N |
| ATOM | 9860 | CA | VAL | E | 682 | −15.629 | 59.635 | 38.236 | 1.00 | 9.25 | E | C |
| ATOM | 9861 | CB | VAL | E | 682 | −15.463 | 60.310 | 39.619 | 1.00 | 7.09 | E | C |
| ATOM | 9862 | CG1 | VAL | E | 682 | −15.363 | 59.240 | 40.712 | 1.00 | 3.75 | E | C |
| ATOM | 9863 | CG2 | VAL | E | 682 | −14.217 | 61.186 | 39.623 | 1.00 | 2.39 | E | C |
| ATOM | 9864 | C | VAL | E | 682 | −16.683 | 58.538 | 38.327 | 1.00 | 8.90 | E | C |
| ATOM | 9865 | O | VAL | E | 682 | −16.360 | 57.365 | 38.506 | 1.00 | 10.08 | E | O |
| ATOM | 9866 | N | ALA | E | 683 | −17.948 | 58.917 | 38.195 | 1.00 | 8.23 | E | N |
| ATOM | 9867 | CA | ALA | E | 683 | −19.036 | 57.941 | 38.249 | 1.00 | 5.16 | E | C |
| ATOM | 9868 | CB | ALA | E | 683 | −20.361 | 58.638 | 38.126 | 1.00 | 2.18 | E | C |
| ATOM | 9869 | C | ALA | E | 683 | −18.883 | 56.930 | 37.125 | 1.00 | 7.35 | E | C |
| ATOM | 9870 | O | ALA | E | 683 | −19.018 | 55.734 | 37.342 | 1.00 | 10.53 | E | O |
| ATOM | 9871 | N | ARG | E | 684 | −18.598 | 57.412 | 35.919 | 1.00 | 10.40 | E | N |
| ATOM | 9872 | CA | ARG | E | 684 | −18.425 | 56.530 | 34.770 | 1.00 | 11.97 | E | C |
| ATOM | 9873 | CB | ARG | E | 684 | −18.135 | 57.349 | 33.511 | 1.00 | 13.15 | E | C |
| ATOM | 9874 | CG | ARG | E | 684 | −17.940 | 56.513 | 32.255 | 1.00 | 13.70 | E | C |
| ATOM | 9875 | CD | ARG | E | 684 | −18.066 | 57.363 | 30.986 | 1.00 | 15.42 | E | C |
| ATOM | 9876 | NE | ARG | E | 684 | −18.064 | 56.534 | 29.787 | 1.00 | 12.84 | E | N |
| ATOM | 9877 | CZ | ARG | E | 684 | −16.963 | 56.084 | 29.200 | 1.00 | 13.97 | E | C |
| ATOM | 9878 | NH1 | ARG | E | 684 | −15.771 | 56.388 | 29.705 | 1.00 | 13.93 | E | N |
| ATOM | 9879 | NH2 | ARG | E | 684 | −17.050 | 55.305 | 28.128 | 1.00 | 13.49 | E | N |
| ATOM | 9880 | C | ARG | E | 684 | −17.277 | 55.563 | 35.036 | 1.00 | 12.49 | E | C |
| ATOM | 9881 | O | ARG | E | 684 | −17.406 | 54.356 | 34.826 | 1.00 | 16.06 | E | O |
| ATOM | 9882 | N | ASN | E | 685 | −16.151 | 56.096 | 35.496 | 1.00 | 12.49 | E | N |
| ATOM | 9883 | CA | ASN | E | 685 | −14.992 | 55.266 | 35.814 | 1.00 | 11.60 | E | C |
| ATOM | 9884 | CB | ASN | E | 685 | −13.895 | 56.107 | 36.472 | 1.00 | 12.68 | E | C |
| ATOM | 9885 | CG | ASN | E | 685 | −13.149 | 56.972 | 35.477 | 1.00 | 15.49 | E | C |
| ATOM | 9886 | OD1 | ASN | E | 685 | −13.485 | 57.004 | 34.291 | 1.00 | 18.67 | E | O |
| ATOM | 9887 | ND2 | ASN | E | 685 | −12.130 | 57.677 | 35.952 | 1.00 | 12.50 | E | N |
| ATOM | 9888 | C | ASN | E | 685 | −15.410 | 54.163 | 36.779 | 1.00 | 10.82 | E | C |
| ATOM | 9889 | O | ASN | E | 685 | −15.081 | 52.995 | 36.587 | 1.00 | 9.17 | E | O |
| ATOM | 9890 | N | SER | E | 686 | −16.139 | 54.541 | 37.822 | 1.00 | 9.91 | E | N |
| ATOM | 9891 | CA | SER | E | 686 | −16.589 | 53.567 | 38.806 | 1.00 | 9.27 | E | C |
| ATOM | 9892 | CB | SER | E | 686 | −17.436 | 54.260 | 39.888 | 1.00 | 5.73 | E | C |
| ATOM | 9893 | OG | SER | E | 686 | −18.814 | 54.277 | 39.570 | 1.00 | 3.98 | E | O |
| ATOM | 9894 | C | SER | E | 686 | −17.352 | 52.405 | 38.160 | 1.00 | 10.18 | E | C |
| ATOM | 9895 | O | SER | E | 686 | −17.145 | 51.250 | 38.534 | 1.00 | 11.55 | E | O |
| ATOM | 9896 | N | VAL | E | 687 | −18.211 | 52.691 | 37.179 | 1.00 | 12.19 | E | N |
| ATOM | 9897 | CA | VAL | E | 687 | −18.962 | 51.622 | 36.516 | 1.00 | 10.91 | E | C |
| ATOM | 9898 | CB | VAL | E | 687 | −20.125 | 52.156 | 35.647 | 1.00 | 10.45 | E | C |
| ATOM | 9899 | CG1 | VAL | E | 687 | −20.941 | 50.984 | 35.111 | 1.00 | 7.78 | E | C |
| ATOM | 9900 | CG2 | VAL | E | 687 | −21.019 | 53.073 | 36.456 | 1.00 | 8.09 | E | C |
| ATOM | 9901 | C | VAL | E | 687 | −18.056 | 50.783 | 35.624 | 1.00 | 12.08 | E | C |
| ATOM | 9902 | O | VAL | E | 687 | −18.167 | 49.556 | 35.577 | 1.00 | 14.91 | E | O |
| ATOM | 9903 | N | LEU | E | 688 | −17.154 | 51.438 | 34.911 | 1.00 | 12.79 | E | N |
| ATOM | 9904 | CA | LEU | E | 688 | −16.241 | 50.717 | 34.035 | 1.00 | 13.11 | E | C |
| ATOM | 9905 | CB | LEU | E | 688 | −15.346 | 51.706 | 33.285 | 1.00 | 12.56 | E | C |
| ATOM | 9906 | CG | LEU | E | 688 | −16.002 | 52.556 | 32.193 | 1.00 | 14.24 | E | C |
| ATOM | 9907 | CD1 | LEU | E | 688 | −15.044 | 53.631 | 31.709 | 1.00 | 7.93 | E | C |
| ATOM | 9908 | CD2 | LEU | E | 688 | −16.405 | 51.658 | 31.048 | 1.00 | 12.28 | E | C |
| ATOM | 9909 | C | LEU | E | 688 | −15.363 | 49.747 | 34.828 | 1.00 | 14.93 | E | C |
| ATOM | 9910 | O | LEU | E | 688 | −15.039 | 48.650 | 34.363 | 1.00 | 18.96 | E | O |
| ATOM | 9911 | N | GLN | E | 689 | −14.984 | 50.155 | 36.033 | 1.00 | 15.06 | E | N |
| ATOM | 9912 | CA | GLN | E | 689 | −14.118 | 49.351 | 36.884 | 1.00 | 12.45 | E | C |
| ATOM | 9913 | CB | GLN | E | 689 | −13.436 | 50.266 | 37.904 | 1.00 | 9.57 | E | C |
| ATOM | 9914 | CG | GLN | E | 689 | −12.842 | 49.543 | 39.090 | 1.00 | 6.15 | E | C |
| ATOM | 9915 | CD | GLN | E | 689 | −12.019 | 50.450 | 39.976 | 1.00 | 6.89 | E | C |
| ATOM | 9916 | OE1 | GLN | E | 689 | −11.116 | 49.998 | 40.661 | 1.00 | 6.93 | E | O |
| ATOM | 9917 | NE2 | GLN | E | 689 | −12.331 | 51.735 | 39.965 | 1.00 | 7.87 | E | N |
| ATOM | 9918 | C | GLN | E | 689 | −14.754 | 48.159 | 37.623 | 1.00 | 14.55 | E | C |
| ATOM | 9919 | O | GLN | E | 689 | −14.113 | 47.118 | 37.779 | 1.00 | 9.91 | E | O |
| ATOM | 9920 | N | CYS | E | 690 | −16.005 | 48.297 | 38.063 | 1.00 | 14.10 | E | N |
| ATOM | 9921 | CA | CYS | E | 690 | −16.650 | 47.238 | 38.836 | 1.00 | 15.95 | E | C |
| ATOM | 9922 | CB | CYS | E | 690 | −17.959 | 47.743 | 39.418 | 1.00 | 16.51 | E | C |
| ATOM | 9923 | SG | CYS | E | 690 | −19.180 | 48.002 | 38.178 | 1.00 | 20.63 | E | S |
| ATOM | 9924 | C | CYS | E | 690 | −16.892 | 45.909 | 38.143 | 1.00 | 15.74 | E | C |
| ATOM | 9925 | O | CYS | E | 690 | −16.526 | 45.728 | 36.997 | 1.00 | 19.37 | E | O |
| ATOM | 9926 | N | GLY | E | 691 | −17.515 | 44.979 | 38.868 | 1.00 | 17.44 | E | N |
| ATOM | 9927 | CA | GLY | E | 691 | −17.789 | 43.654 | 38.338 | 1.00 | 14.56 | E | C |
| ATOM | 9928 | C | GLY | E | 691 | −19.209 | 43.411 | 37.847 | 1.00 | 17.98 | E | C |
| ATOM | 9929 | O | GLY | E | 691 | −19.590 | 42.260 | 37.589 | 1.00 | 19.41 | E | O |
| ATOM | 9930 | N | ILE | E | 692 | −19.997 | 44.477 | 37.716 | 1.00 | 14.89 | E | N |
| ATOM | 9931 | CA | ILE | E | 692 | −21.361 | 44.350 | 37.227 | 1.00 | 14.50 | E | C |
| ATOM | 9932 | CB | ILE | E | 692 | −22.009 | 45.734 | 37.073 | 1.00 | 15.26 | E | C |
| ATOM | 9933 | CG2 | ILE | E | 692 | −23.368 | 45.616 | 36.376 | 1.00 | 15.94 | E | C |
| ATOM | 9934 | CG1 | ILE | E | 692 | −22.162 | 46.375 | 38.454 | 1.00 | 13.01 | E | C |
| ATOM | 9935 | CD1 | ILE | E | 692 | −23.079 | 47.597 | 38.486 | 1.00 | 13.97 | E | C |
| ATOM | 9936 | C | ILE | E | 692 | −21.329 | 43.631 | 35.874 | 1.00 | 15.30 | E | C |
| ATOM | 9937 | O | ILE | E | 692 | −20.312 | 43.636 | 35.188 | 1.00 | 14.78 | E | O |
| ATOM | 9938 | N | SER | E | 693 | −22.438 | 43.007 | 35.491 | 1.00 | 16.82 | E | N |
| ATOM | 9939 | CA | SER | E | 693 | −22.492 | 42.276 | 34.229 | 1.00 | 16.91 | E | C |
| ATOM | 9940 | CB | SER | E | 693 | −23.742 | 41.390 | 34.186 | 1.00 | 16.57 | E | C |
| ATOM | 9941 | OG | SER | E | 693 | −24.925 | 42.167 | 34.056 | 1.00 | 19.12 | E | O |
| ATOM | 9942 | C | SER | E | 693 | −22.464 | 43.188 | 33.009 | 1.00 | 19.22 | E | C |
| ATOM | 9943 | O | SER | E | 693 | −22.811 | 44.368 | 33.093 | 1.00 | 20.15 | E | O |
| ATOM | 9944 | N | HIS | E | 694 | −22.048 | 42.623 | 31.878 | 1.00 | 21.51 | E | N |
| ATOM | 9945 | CA | HIS | E | 694 | −21.964 | 43.347 | 30.615 | 1.00 | 24.03 | E | C |
| ATOM | 9946 | CB | HIS | E | 694 | −21.448 | 42.423 | 29.513 | 1.00 | 24.66 | E | C |
| ATOM | 9947 | CG | HIS | E | 694 | −21.419 | 43.060 | 28.159 | 1.00 | 27.58 | E | C |
| ATOM | 9948 | CD2 | HIS | E | 694 | −20.526 | 43.903 | 27.589 | 1.00 | 26.12 | E | C |
| ATOM | 9949 | ND1 | HIS | E | 694 | −22.415 | 42.869 | 27.222 | 1.00 | 29.26 | E | N |
| ATOM | 9950 | CE1 | HIS | E | 694 | −22.134 | 43.568 | 26.137 | 1.00 | 27.31 | E | C |
| ATOM | 9951 | NE2 | HIS | E | 694 | −20.995 | 44.203 | 26.334 | 1.00 | 25.80 | E | N |
| ATOM | 9952 | C | HIS | E | 694 | −23.303 | 43.926 | 30.187 | 1.00 | 24.47 | E | C |
| ATOM | 9953 | O | HIS | E | 694 | −23.398 | 45.103 | 29.854 | 1.00 | 24.97 | E | O |
| ATOM | 9954 | N | GLU | E | 695 | −24.337 | 43.095 | 30.189 | 1.00 | 27.06 | E | N |
| ATOM | 9955 | CA | GLU | E | 695 | −25.660 | 43.550 | 29.795 | 1.00 | 30.61 | E | C |
| ATOM | 9956 | CB | GLU | E | 695 | −26.693 | 42.434 | 29.992 | 1.00 | 37.50 | E | C |
| ATOM | 9957 | CG | GLU | E | 695 | −28.099 | 42.785 | 29.498 | 1.00 | 47.73 | E | C |
| ATOM | 9958 | CD | GLU | E | 695 | −29.199 | 42.335 | 30.460 | 1.00 | 55.09 | E | C |
| ATOM | 9959 | OE1 | GLU | E | 695 | −29.717 | 41.206 | 30.289 | 1.00 | 58.35 | E | O |
| ATOM | 9960 | OE2 | GLU | E | 695 | −29.546 | 43.109 | 31.386 | 1.00 | 59.08 | E | O |
| ATOM | 9961 | C | GLU | E | 695 | −26.065 | 44.778 | 30.596 | 1.00 | 28.95 | E | C |
| ATOM | 9962 | O | GLU | E | 695 | −26.517 | 45.767 | 30.031 | 1.00 | 31.39 | E | O |
| ATOM | 9963 | N | GLU | E | 696 | −25.893 | 44.724 | 31.911 | 1.00 | 28.02 | E | N |
| ATOM | 9964 | CA | GLU | E | 696 | −26.259 | 45.853 | 32.760 | 1.00 | 26.25 | E | C |
| ATOM | 9965 | CB | GLU | E | 696 | −26.179 | 45.452 | 34.224 | 1.00 | 29.73 | E | C |
| ATOM | 9966 | CG | GLU | E | 696 | −27.525 | 45.153 | 34.834 | 1.00 | 37.30 | E | C |
| ATOM | 9967 | CD | GLU | E | 696 | −27.401 | 44.182 | 35.983 | 1.00 | 44.01 | E | C |
| ATOM | 9968 | OE1 | GLU | E | 696 | −27.796 | 44.546 | 37.125 | 1.00 | 46.29 | E | O |
| ATOM | 9969 | OE2 | GLU | E | 696 | −26.898 | 43.058 | 35.739 | 1.00 | 45.16 | E | O |
| ATOM | 9970 | C | GLU | E | 696 | −25.387 | 47.073 | 32.530 | 1.00 | 23.17 | E | C |
| ATOM | 9971 | O | GLU | E | 696 | −25.887 | 48.195 | 32.478 | 1.00 | 18.23 | E | O |
| ATOM | 9972 | N | LYS | E | 697 | −24.080 | 46.856 | 32.408 | 1.00 | 22.25 | E | N |
| ATOM | 9973 | CA | LYS | E | 697 | −23.157 | 47.964 | 32.170 | 1.00 | 22.56 | E | C |
| ATOM | 9974 | CB | LYS | E | 697 | −21.722 | 47.449 | 32.023 | 1.00 | 18.55 | E | C |
| ATOM | 9975 | CG | LYS | E | 697 | −20.961 | 47.343 | 33.339 | 1.00 | 17.35 | E | C |
| ATOM | 9976 | CD | LYS | E | 697 | −19.468 | 47.152 | 33.106 | 1.00 | 15.25 | E | C |
| ATOM | 9977 | CE | LYS | E | 697 | −18.747 | 46.786 | 34.396 | 1.00 | 16.98 | E | C |
| ATOM | 9978 | NZ | LYS | E | 697 | −17.272 | 46.690 | 34.204 | 1.00 | 18.33 | E | N |
| ATOM | 9979 | C | LYS | E | 697 | −23.578 | 48.703 | 30.902 | 1.00 | 24.08 | E | C |
| ATOM | 9980 | O | LYS | E | 697 | −23.655 | 49.933 | 30.884 | 1.00 | 27.81 | E | O |
| ATOM | 9981 | N | ALA | E | 698 | −23.868 | 47.950 | 29.846 | 1.00 | 22.26 | E | N |
| ATOM | 9982 | CA | ALA | E | 698 | −24.289 | 48.537 | 28.578 | 1.00 | 23.46 | E | C |
| ATOM | 9983 | CB | ALA | E | 698 | −24.583 | 47.434 | 27.567 | 1.00 | 23.18 | E | C |
| ATOM | 9984 | C | ALA | E | 698 | −25.522 | 49.409 | 28.760 | 1.00 | 22.41 | E | C |
| ATOM | 9985 | O | ALA | E | 698 | −25.703 | 50.401 | 28.057 | 1.00 | 22.73 | E | O |
| ATOM | 9986 | N | LYS | E | 699 | −26.369 | 49.030 | 29.711 | 1.00 | 24.61 | E | N |
| ATOM | 9987 | CA | LYS | E | 699 | −27.600 | 49.761 | 29.995 | 1.00 | 24.26 | E | C |
| ATOM | 9988 | CB | LYS | E | 699 | −28.575 | 48.847 | 30.747 | 1.00 | 25.75 | E | C |
| ATOM | 9989 | CG | LYS | E | 699 | −29.654 | 49.571 | 31.541 | 1.00 | 31.55 | E | C |
| ATOM | 9990 | CD | LYS | E | 699 | −30.523 | 48.584 | 32.327 | 1.00 | 36.24 | E | C |
| ATOM | 9991 | CE | LYS | E | 699 | −31.268 | 49.267 | 33.469 | 1.00 | 36.67 | E | C |
| ATOM | 9992 | NZ | LYS | E | 699 | −32.466 | 50.036 | 33.000 | 1.00 | 40.21 | E | N |
| ATOM | 9993 | C | LYS | E | 699 | −27.350 | 51.045 | 30.792 | 1.00 | 23.39 | E | C |
| ATOM | 9994 | O | LYS | E | 699 | −28.150 | 51.984 | 30.726 | 1.00 | 22.58 | E | O |
| ATOM | 9995 | N | PHE | E | 700 | −26.246 | 51.093 | 31.536 | 1.00 | 20.77 | E | N |
| ATOM | 9996 | CA | PHE | E | 700 | −25.927 | 52.279 | 32.328 | 1.00 | 19.17 | E | C |
| ATOM | 9997 | CB | PHE | E | 700 | −25.200 | 51.912 | 33.633 | 1.00 | 18.28 | E | C |
| ATOM | 9998 | CG | PHE | E | 700 | −25.953 | 50.967 | 34.522 | 1.00 | 19.00 | E | C |
| ATOM | 9999 | CD1 | PHE | E | 700 | −27.343 | 50.953 | 34.547 | 1.00 | 18.25 | E | C |
| ATOM | 10000 | CD2 | PHE | E | 700 | −25.264 | 50.072 | 35.331 | 1.00 | 17.96 | E | C |
| ATOM | 10001 | CE1 | PHE | E | 700 | −28.029 | 50.061 | 35.358 | 1.00 | 12.08 | E | C |
| ATOM | 10002 | CE2 | PHE | E | 700 | −25.948 | 49.178 | 36.145 | 1.00 | 16.33 | E | C |
| ATOM | 10003 | CZ | PHE | E | 700 | −27.333 | 49.175 | 36.155 | 1.00 | 12.75 | E | C |
| ATOM | 10004 | C | PHE | E | 700 | −25.025 | 53.231 | 31.565 | 1.00 | 18.88 | E | C |
| ATOM | 10005 | O | PHE | E | 700 | −25.169 | 54.449 | 31.669 | 1.00 | 17.27 | E | O |
| ATOM | 10006 | N | LEU | E | 701 | −24.086 | 52.666 | 30.812 | 1.00 | 20.39 | E | N |
| ATOM | 10007 | CA | LEU | E | 701 | −23.108 | 53.458 | 30.061 | 1.00 | 22.66 | E | C |
| ATOM | 10008 | CB | LEU | E | 701 | −21.708 | 52.872 | 30.275 | 1.00 | 20.26 | E | C |
| ATOM | 10009 | CG | LEU | E | 701 | −21.191 | 52.668 | 31.702 | 1.00 | 18.21 | E | C |
| ATOM | 10010 | CD1 | LEU | E | 701 | −19.801 | 52.058 | 31.651 | 1.00 | 12.75 | E | C |
| ATOM | 10011 | CD2 | LEU | E | 701 | −21.146 | 53.997 | 32.431 | 1.00 | 18.01 | E | C |
| ATOM | 10012 | C | LEU | E | 701 | −23.331 | 53.606 | 28.555 | 1.00 | 22.77 | E | C |
| ATOM | 10013 | O | LEU | E | 701 | −22.736 | 54.483 | 27.930 | 1.00 | 25.38 | E | O |
| ATOM | 10014 | N | GLY | E | 702 | −24.175 | 52.754 | 27.981 | 1.00 | 25.01 | E | N |
| ATOM | 10015 | CA | GLY | E | 702 | −24.422 | 52.784 | 26.546 | 1.00 | 26.17 | E | C |
| ATOM | 10016 | C | GLY | E | 702 | −23.911 | 51.472 | 25.966 | 1.00 | 27.31 | E | C |
| ATOM | 10017 | O | GLY | E | 702 | −23.102 | 50.803 | 26.600 | 1.00 | 29.76 | E | O |
| ATOM | 10018 | N | ASN | E | 703 | −24.348 | 51.099 | 24.767 | 1.00 | 27.32 | E | N |
| ATOM | 10019 | CA | ASN | E | 703 | −23.923 | 49.828 | 24.172 | 1.00 | 26.37 | E | C |
| ATOM | 10020 | CB | ASN | E | 703 | −24.845 | 49.475 | 23.008 | 1.00 | 28.40 | E | C |
| ATOM | 10021 | CG | ASN | E | 703 | −26.235 | 49.106 | 23.465 | 1.00 | 31.97 | E | C |
| ATOM | 10022 | OD1 | ASN | E | 703 | −26.439 | 48.073 | 24.103 | 1.00 | 32.69 | E | O |
| ATOM | 10023 | ND2 | ASN | E | 703 | −27.205 | 49.954 | 23.145 | 1.00 | 34.50 | E | N |
| ATOM | 10024 | C | ASN | E | 703 | −22.470 | 49.701 | 23.708 | 1.00 | 25.16 | E | C |
| ATOM | 10025 | O | ASN | E | 703 | −21.983 | 48.590 | 23.520 | 1.00 | 21.73 | E | O |
| ATOM | 10026 | N | ASN | E | 704 | −21.777 | 50.823 | 23.539 | 1.00 | 23.79 | E | N |
| ATOM | 10027 | CA | ASN | E | 704 | −20.393 | 50.797 | 23.073 | 1.00 | 23.20 | E | C |
| ATOM | 10028 | CB | ASN | E | 704 | −20.215 | 51.810 | 21.946 | 1.00 | 30.52 | E | C |
| ATOM | 10029 | CG | ASN | E | 704 | −20.063 | 51.159 | 20.597 | 1.00 | 34.40 | E | C |
| ATOM | 10030 | OD1 | ASN | E | 704 | −18.941 | 50.958 | 20.115 | 1.00 | 34.39 | E | O |
| ATOM | 10031 | ND2 | ASN | E | 704 | −21.192 | 50.827 | 19.968 | 1.00 | 35.47 | E | N |
| ATOM | 10032 | C | ASN | E | 704 | −19.354 | 51.093 | 24.143 | 1.00 | 21.15 | E | C |
| ATOM | 10033 | O | ASN | E | 704 | −18.192 | 51.335 | 23.826 | 1.00 | 18.76 | E | O |
| ATOM | 10034 | N | TYR | E | 705 | −19.771 | 51.062 | 25.402 | 1.00 | 21.16 | E | N |
| ATOM | 10035 | CA | TYR | E | 705 | −18.886 | 51.361 | 26.522 | 1.00 | 19.53 | E | C |
| ATOM | 10036 | CB | TYR | E | 705 | −19.613 | 51.058 | 27.845 | 1.00 | 18.01 | E | C |
| ATOM | 10037 | CG | TYR | E | 705 | −19.579 | 49.611 | 28.277 | 1.00 | 16.95 | E | C |
| ATOM | 10038 | CD1 | TYR | E | 705 | −20.620 | 48.740 | 27.951 | 1.00 | 16.11 | E | C |
| ATOM | 10039 | CE1 | TYR | E | 705 | −20.587 | 47.399 | 28.351 | 1.00 | 16.97 | E | C |
| ATOM | 10040 | CD2 | TYR | E | 705 | −18.500 | 49.109 | 29.015 | 1.00 | 15.34 | E | C |
| ATOM | 10041 | CE2 | TYR | E | 705 | −18.458 | 47.779 | 29.418 | 1.00 | 15.68 | E | C |
| ATOM | 10042 | CZ | TYR | E | 705 | −19.502 | 46.930 | 29.085 | 1.00 | 18.28 | E | C |
| ATOM | 10043 | OH | TYR | E | 705 | −19.458 | 45.617 | 29.505 | 1.00 | 21.83 | E | O |
| ATOM | 10044 | C | TYR | E | 705 | −17.507 | 50.688 | 26.499 | 1.00 | 18.21 | E | C |
| ATOM | 10045 | O | TYR | E | 705 | −16.543 | 51.240 | 27.027 | 1.00 | 19.40 | E | O |
| ATOM | 10046 | N | LEU | E | 706 | −17.394 | 49.518 | 25.880 | 1.00 | 17.50 | E | N |
| ATOM | 10047 | CA | LEU | E | 706 | −16.107 | 48.828 | 25.844 | 1.00 | 19.57 | E | C |
| ATOM | 10048 | CB | LEU | E | 706 | −16.303 | 47.353 | 25.471 | 1.00 | 17.79 | E | C |
| ATOM | 10049 | CG | LEU | E | 706 | −16.885 | 46.428 | 26.553 | 1.00 | 20.30 | E | C |
| ATOM | 10050 | CD1 | LEU | E | 706 | −17.296 | 45.102 | 25.921 | 1.00 | 14.96 | E | C |
| ATOM | 10051 | CD2 | LEU | E | 706 | −15.869 | 46.198 | 27.667 | 1.00 | 12.13 | E | C |
| ATOM | 10052 | C | LEU | E | 706 | −15.106 | 49.476 | 24.883 | 1.00 | 23.16 | E | C |
| ATOM | 10053 | O | LEU | E | 706 | −13.901 | 49.217 | 24.959 | 1.00 | 22.79 | E | O |
| ATOM | 10054 | N | GLU | E | 707 | −15.602 | 50.318 | 23.982 | 1.00 | 25.48 | E | N |
| ATOM | 10055 | CA | GLU | E | 707 | −14.742 | 50.999 | 23.018 | 1.00 | 26.97 | E | C |
| ATOM | 10056 | CB | GLU | E | 707 | −15.569 | 51.456 | 21.812 | 1.00 | 31.15 | E | C |
| ATOM | 10057 | CG | GLU | E | 707 | −15.977 | 50.327 | 20.879 | 1.00 | 37.00 | E | C |
| ATOM | 10058 | CD | GLU | E | 707 | −14.796 | 49.467 | 20.473 | 1.00 | 42.72 | E | C |
| ATOM | 10059 | OE1 | GLU | E | 707 | −14.800 | 48.253 | 20.787 | 1.00 | 45.66 | E | O |
| ATOM | 10060 | OE2 | GLU | E | 707 | −13.861 | 50.009 | 19.841 | 1.00 | 44.74 | E | O |
| ATOM | 10061 | C | GLU | E | 707 | −14.086 | 52.203 | 23.684 | 1.00 | 25.32 | E | C |
| ATOM | 10062 | O | GLU | E | 707 | −14.740 | 52.940 | 24.416 | 1.00 | 26.60 | E | O |
| ATOM | 10063 | N | GLU | E | 708 | −12.800 | 52.410 | 23.419 | 1.00 | 25.72 | E | N |
| ATOM | 10064 | CA | GLU | E | 708 | −12.062 | 53.523 | 24.016 | 1.00 | 25.76 | E | C |
| ATOM | 10065 | CB | GLU | E | 708 | −10.571 | 53.178 | 24.109 | 1.00 | 27.15 | E | C |
| ATOM | 10066 | CG | GLU | E | 708 | −10.265 | 51.695 | 23.987 | 1.00 | 32.20 | E | C |
| ATOM | 10067 | CD | GLU | E | 708 | −9.357 | 51.181 | 25.089 | 1.00 | 32.83 | E | C |
| ATOM | 10068 | OE1 | GLU | E | 708 | −8.165 | 51.538 | 25.084 | 1.00 | 32.13 | E | O |
| ATOM | 10069 | OE2 | GLU | E | 708 | −9.832 | 50.412 | 25.955 | 1.00 | 35.66 | E | O |
| ATOM | 10070 | C | GLU | E | 708 | −12.226 | 54.852 | 23.278 | 1.00 | 23.83 | E | C |
| ATOM | 10071 | O | GLU | E | 708 | −12.343 | 54.884 | 22.053 | 1.00 | 24.51 | E | O |
| ATOM | 10072 | N | GLY | E | 709 | −12.232 | 55.947 | 24.035 | 1.00 | 19.99 | E | N |
| ATOM | 10073 | CA | GLY | E | 709 | −12.368 | 57.261 | 23.439 | 1.00 | 15.35 | E | C |
| ATOM | 10074 | C | GLY | E | 709 | −13.799 | 57.747 | 23.360 | 1.00 | 15.01 | E | C |
| ATOM | 10075 | O | GLY | E | 709 | −14.708 | 57.100 | 23.875 | 1.00 | 19.59 | E | O |
| ATOM | 10076 | N | PRO | E | 710 | −14.034 | 58.890 | 22.708 | 1.00 | 12.95 | E | N |
| ATOM | 10077 | CD | PRO | E | 710 | −13.004 | 59.717 | 22.058 | 1.00 | 10.41 | E | C |
| ATOM | 10078 | CA | PRO | E | 710 | −15.373 | 59.469 | 22.561 | 1.00 | 14.26 | E | C |
| ATOM | 10079 | CB | PRO | E | 710 | −15.146 | 60.665 | 21.642 | 1.00 | 12.26 | E | C |
| ATOM | 10080 | CG | PRO | E | 710 | −13.710 | 61.006 | 21.820 | 1.00 | 10.13 | E | C |
| ATOM | 10081 | C | PRO | E | 710 | −16.403 | 58.509 | 21.978 | 1.00 | 15.04 | E | C |
| ATOM | 10082 | O | PRO | E | 710 | −17.589 | 58.579 | 22.290 | 1.00 | 17.01 | E | O |
| ATOM | 10083 | N | ILE | E | 711 | −15.936 | 57.616 | 21.123 | 1.00 | 16.55 | E | N |
| ATOM | 10084 | CA | ILE | E | 711 | −16.805 | 56.665 | 20.468 | 1.00 | 17.32 | E | C |
| ATOM | 10085 | CB | ILE | E | 711 | −16.003 | 55.821 | 19.455 | 1.00 | 20.11 | E | C |
| ATOM | 10086 | CG2 | ILE | E | 711 | −15.242 | 54.721 | 20.172 | 1.00 | 21.76 | E | C |
| ATOM | 10087 | CG1 | ILE | E | 711 | −16.946 | 55.249 | 18.397 | 1.00 | 21.79 | E | C |
| ATOM | 10088 | CD1 | ILE | E | 711 | −17.804 | 56.299 | 17.694 | 1.00 | 20.78 | E | C |
| ATOM | 10089 | C | ILE | E | 711 | −17.537 | 55.755 | 21.443 | 1.00 | 19.75 | E | C |
| ATOM | 10090 | O | ILE | E | 711 | −18.680 | 55.359 | 21.193 | 1.00 | 20.12 | E | O |
| ATOM | 10091 | N | GLY | E | 712 | −16.897 | 55.441 | 22.565 | 1.00 | 19.20 | E | N |
| ATOM | 10092 | CA | GLY | E | 712 | −17.528 | 54.568 | 23.540 | 1.00 | 16.48 | E | C |
| ATOM | 10093 | C | GLY | E | 712 | −18.382 | 55.253 | 24.594 | 1.00 | 16.59 | E | C |
| ATOM | 10094 | O | GLY | E | 712 | −18.885 | 54.593 | 25.501 | 1.00 | 19.74 | E | O |
| ATOM | 10095 | N | ASN | E | 713 | −18.567 | 56.564 | 24.494 | 1.00 | 13.51 | E | N |
| ATOM | 10096 | CA | ASN | E | 713 | −19.367 | 57.261 | 25.487 | 1.00 | 12.48 | E | C |
| ATOM | 10097 | CB | ASN | E | 713 | −18.613 | 58.469 | 26.047 | 1.00 | 10.00 | E | C |
| ATOM | 10098 | CG | ASN | E | 713 | −19.473 | 59.309 | 26.984 | 1.00 | 9.27 | E | C |
| ATOM | 10099 | OD1 | ASN | E | 713 | −19.646 | 60.504 | 26.779 | 1.00 | 10.84 | E | O |
| ATOM | 10100 | ND2 | ASN | E | 713 | −20.021 | 58.677 | 28.018 | 1.00 | 6.33 | E | N |
| ATOM | 10101 | C | ASN | E | 713 | −20.707 | 57.729 | 24.962 | 1.00 | 14.31 | E | C |
| ATOM | 10102 | O | ASN | E | 713 | −20.784 | 58.377 | 23.922 | 1.00 | 14.75 | E | O |
| ATOM | 10103 | N | ASP | E | 714 | −21.766 | 57.403 | 25.696 | 1.00 | 15.22 | E | N |
| ATOM | 10104 | CA | ASP | E | 714 | −23.110 | 57.826 | 25.328 | 1.00 | 15.24 | E | C |
| ATOM | 10105 | CB | ASP | E | 714 | −24.066 | 56.634 | 25.334 | 1.00 | 17.21 | E | C |
| ATOM | 10106 | CG | ASP | E | 714 | −25.459 | 56.996 | 24.851 | 1.00 | 20.12 | E | C |
| ATOM | 10107 | OD1 | ASP | E | 714 | −25.768 | 58.202 | 24.714 | 1.00 | 20.68 | E | O |
| ATOM | 10108 | OD2 | ASP | E | 714 | −26.252 | 56.065 | 24.610 | 1.00 | 21.39 | E | O |
| ATOM | 10109 | C | ASP | E | 714 | −23.512 | 58.830 | 26.396 | 1.00 | 16.65 | E | C |
| ATOM | 10110 | O | ASP | E | 714 | −23.993 | 58.449 | 27.461 | 1.00 | 18.05 | E | O |
| ATOM | 10111 | N | ILE | E | 715 | −23.297 | 60.111 | 26.115 | 1.00 | 16.41 | E | N |
| ATOM | 10112 | CA | ILE | E | 715 | −23.614 | 61.162 | 27.071 | 1.00 | 15.64 | E | C |
| ATOM | 10113 | CB | ILE | E | 715 | −23.312 | 62.560 | 26.481 | 1.00 | 17.18 | E | C |
| ATOM | 10114 | CG2 | ILE | E | 715 | −24.287 | 62.880 | 25.345 | 1.00 | 13.84 | E | C |
| ATOM | 10115 | CG1 | ILE | E | 715 | −23.393 | 63.619 | 27.587 | 1.00 | 14.10 | E | C |
| ATOM | 10116 | CD1 | ILE | E | 715 | −23.075 | 65.027 | 27.110 | 1.00 | 11.61 | E | C |
| ATOM | 10117 | C | ILE | E | 715 | −25.050 | 61.126 | 27.554 | 1.00 | 15.89 | E | C |
| ATOM | 10118 | O | ILE | E | 715 | −25.353 | 61.618 | 28.635 | 1.00 | 19.89 | E | O |
| ATOM | 10119 | N | ARG | E | 716 | −25.940 | 60.541 | 26.768 | 1.00 | 18.33 | E | N |
| ATOM | 10120 | CA | ARG | E | 716 | −27.342 | 60.479 | 27.165 | 1.00 | 20.91 | E | C |
| ATOM | 10121 | CB | ARG | E | 716 | −28.194 | 59.899 | 26.030 | 1.00 | 25.29 | E | C |
| ATOM | 10122 | CG | ARG | E | 716 | −28.598 | 60.912 | 24.972 | 1.00 | 27.93 | E | C |
| ATOM | 10123 | CD | ARG | E | 716 | −29.298 | 60.248 | 23.800 | 1.00 | 36.42 | E | C |
| ATOM | 10124 | NE | ARG | E | 716 | −28.610 | 59.039 | 23.347 | 1.00 | 44.20 | E | N |
| ATOM | 10125 | CZ | ARG | E | 716 | −29.164 | 58.110 | 22.569 | 1.00 | 45.15 | E | C |
| ATOM | 10126 | NH1 | ARG | E | 716 | −30.418 | 58.252 | 22.156 | 1.00 | 44.13 | E | N |
| ATOM | 10127 | NH2 | ARG | E | 716 | −28.467 | 57.038 | 22.207 | 1.00 | 43.92 | E | N |
| ATOM | 10128 | C | ARG | E | 716 | −27.487 | 59.612 | 28.398 | 1.00 | 18.75 | E | C |
| ATOM | 10129 | O | ARG | E | 716 | −28.472 | 59.701 | 29.117 | 1.00 | 20.54 | E | O |
| ATOM | 10130 | N | LYS | E | 717 | −26.486 | 58.778 | 28.641 | 1.00 | 19.24 | E | N |
| ATOM | 10131 | CA | LYS | E | 717 | −26.503 | 57.871 | 29.775 | 1.00 | 19.59 | E | C |
| ATOM | 10132 | CB | LYS | E | 717 | −26.265 | 56.442 | 29.280 | 1.00 | 20.28 | E | C |
| ATOM | 10133 | CG | LYS | E | 717 | −27.551 | 55.685 | 28.946 | 1.00 | 22.63 | E | C |
| ATOM | 10134 | CD | LYS | E | 717 | −27.268 | 54.522 | 28.025 | 1.00 | 26.14 | E | C |
| ATOM | 10135 | CE | LYS | E | 717 | −28.510 | 53.679 | 27.781 | 1.00 | 29.98 | E | C |
| ATOM | 10136 | NZ | LYS | E | 717 | −28.173 | 52.393 | 27.066 | 1.00 | 31.75 | E | N |
| ATOM | 10137 | C | LYS | E | 717 | −25.499 | 58.211 | 30.880 | 1.00 | 19.85 | E | C |
| ATOM | 10138 | O | LYS | E | 717 | −25.772 | 57.990 | 32.064 | 1.00 | 21.47 | E | O |
| ATOM | 10139 | N | THR | E | 718 | −24.350 | 58.761 | 30.499 | 1.00 | 17.40 | E | N |
| ATOM | 10140 | CA | THR | E | 718 | −23.310 | 59.098 | 31.461 | 1.00 | 15.63 | E | C |
| ATOM | 10141 | CB | THR | E | 718 | −21.939 | 58.726 | 30.911 | 1.00 | 16.82 | E | C |
| ATOM | 10142 | OG1 | THR | E | 718 | −21.622 | 59.600 | 29.818 | 1.00 | 17.62 | E | O |
| ATOM | 10143 | CG2 | THR | E | 718 | −21.930 | 57.287 | 30.427 | 1.00 | 13.40 | E | C |
| ATOM | 10144 | C | THR | E | 718 | −23.225 | 60.562 | 31.903 | 1.00 | 17.39 | E | C |
| ATOM | 10145 | O | THR | E | 718 | −22.696 | 60.854 | 32.970 | 1.00 | 17.05 | E | O |
| ATOM | 10146 | N | ASN | E | 719 | −23.738 | 61.480 | 31.092 | 1.00 | 16.36 | E | N |
| ATOM | 10147 | CA | ASN | E | 719 | −23.667 | 62.906 | 31.399 | 1.00 | 14.18 | E | C |
| ATOM | 10148 | CB | ASN | E | 719 | −24.358 | 63.234 | 32.723 | 1.00 | 14.36 | E | C |
| ATOM | 10149 | CG | ASN | E | 719 | −24.890 | 64.671 | 32.767 | 1.00 | 15.99 | E | C |
| ATOM | 10150 | OD1 | ASN | E | 719 | −25.614 | 65.115 | 31.872 | 1.00 | 18.91 | E | O |
| ATOM | 10151 | ND2 | ASN | E | 719 | −24.533 | 65.397 | 33.810 | 1.00 | 16.58 | E | N |
| ATOM | 10152 | C | ASN | E | 719 | −22.216 | 63.386 | 31.441 | 1.00 | 13.41 | E | C |
| ATOM | 10153 | O | ASN | E | 719 | −21.881 | 64.340 | 32.147 | 1.00 | 13.98 | E | O |
| ATOM | 10154 | N | VAL | E | 720 | −21.359 | 62.714 | 30.680 | 1.00 | 12.60 | E | N |
| ATOM | 10155 | CA | VAL | E | 720 | −19.954 | 63.080 | 30.589 | 1.00 | 13.36 | E | C |
| ATOM | 10156 | CB | VAL | E | 720 | −19.046 | 61.838 | 30.658 | 1.00 | 12.76 | E | C |
| ATOM | 10157 | CG1 | VAL | E | 720 | −17.592 | 62.243 | 30.445 | 1.00 | 13.09 | E | C |
| ATOM | 10158 | CG2 | VAL | E | 720 | −19.206 | 61.156 | 32.001 | 1.00 | 10.26 | E | C |
| ATOM | 10159 | C | VAL | E | 720 | −19.773 | 63.762 | 29.231 | 1.00 | 15.26 | E | C |
| ATOM | 10160 | O | VAL | E | 720 | −20.101 | 63.186 | 28.194 | 1.00 | 14.80 | E | O |
| ATOM | 10161 | N | ALA | E | 721 | −19.259 | 64.988 | 29.242 | 1.00 | 13.90 | E | N |
| ATOM | 10162 | CA | ALA | E | 721 | −19.055 | 65.755 | 28.017 | 1.00 | 10.31 | E | C |
| ATOM | 10163 | CB | ALA | E | 721 | −18.444 | 67.106 | 28.351 | 1.00 | 8.89 | E | C |
| ATOM | 10164 | C | ALA | E | 721 | −18.170 | 65.020 | 27.024 | 1.00 | 9.64 | E | C |
| ATOM | 10165 | O | ALA | E | 721 | −17.223 | 64.348 | 27.409 | 1.00 | 10.02 | E | O |
| ATOM | 10166 | N | GLN | E | 722 | −18.478 | 65.148 | 25.741 | 1.00 | 11.46 | E | N |
| ATOM | 10167 | CA | GLN | E | 722 | −17.674 | 64.492 | 24.725 | 1.00 | 11.24 | E | C |
| ATOM | 10168 | CB | GLN | E | 722 | −18.431 | 64.446 | 23.402 | 1.00 | 13.02 | E | C |
| ATOM | 10169 | CG | GLN | E | 722 | −19.469 | 63.326 | 23.329 | 1.00 | 13.92 | E | C |
| ATOM | 10170 | CD | GLN | E | 722 | −18.863 | 61.930 | 23.444 | 1.00 | 15.75 | E | C |
| ATOM | 10171 | OE1 | GLN | E | 722 | −18.808 | 61.180 | 22.472 | 1.00 | 18.92 | E | O |
| ATOM | 10172 | NE2 | GLN | E | 722 | −18.416 | 61.577 | 24.636 | 1.00 | 16.80 | E | N |
| ATOM | 10173 | C | GLN | E | 722 | −16.359 | 65.250 | 24.581 | 1.00 | 12.14 | E | C |
| ATOM | 10174 | O | GLN | E | 722 | −15.356 | 64.711 | 24.099 | 1.00 | 13.65 | E | O |
| ATOM | 10175 | N | ILE | E | 723 | −16.361 | 66.505 | 25.020 | 1.00 | 12.98 | E | N |
| ATOM | 10176 | CA | ILE | E | 723 | −15.160 | 67.324 | 24.976 | 1.00 | 12.88 | E | C |
| ATOM | 10177 | CB | ILE | E | 723 | −15.456 | 68.768 | 25.413 | 1.00 | 15.13 | E | C |
| ATOM | 10178 | CG2 | ILE | E | 723 | −14.142 | 69.526 | 25.636 | 1.00 | 11.59 | E | C |
| ATOM | 10179 | CG1 | ILE | E | 723 | −16.313 | 69.463 | 24.349 | 1.00 | 14.60 | E | C |
| ATOM | 10180 | CD1 | ILE | E | 723 | −16.639 | 70.915 | 24.661 | 1.00 | 14.99 | E | C |
| ATOM | 10181 | C | ILE | E | 723 | −14.143 | 66.722 | 25.941 | 1.00 | 14.66 | E | C |
| ATOM | 10182 | O | ILE | E | 723 | −12.939 | 66.709 | 25.667 | 1.00 | 17.85 | E | O |
| ATOM | 10183 | N | ARG | E | 724 | −14.633 | 66.215 | 27.072 | 1.00 | 12.32 | E | N |
| ATOM | 10184 | CA | ARG | E | 724 | −13.774 | 65.609 | 28.075 | 1.00 | 9.30 | E | C |
| ATOM | 10185 | CB | ARG | E | 724 | −14.554 | 65.407 | 29.383 | 1.00 | 13.21 | E | C |
| ATOM | 10186 | CG | ARG | E | 724 | −13.758 | 64.776 | 30.542 | 1.00 | 11.65 | E | C |
| ATOM | 10187 | CD | ARG | E | 724 | −12.563 | 65.632 | 30.986 | 1.00 | 12.43 | E | C |
| ATOM | 10188 | NE | ARG | E | 724 | −12.968 | 66.922 | 31.537 | 1.00 | 13.26 | E | N |
| ATOM | 10189 | CZ | ARG | E | 724 | −13.255 | 67.145 | 32.819 | 1.00 | 15.09 | E | C |
| ATOM | 10190 | NH1 | ARG | E | 724 | −13.187 | 66.163 | 33.715 | 1.00 | 12.83 | E | N |
| ATOM | 10191 | NH2 | ARG | E | 724 | −13.623 | 68.356 | 33.204 | 1.00 | 10.68 | E | N |
| ATOM | 10192 | C | ARG | E | 724 | −13.246 | 64.283 | 27.557 | 1.00 | 8.65 | E | C |
| ATOM | 10193 | O | ARG | E | 724 | −12.058 | 63.982 | 27.694 | 1.00 | 9.68 | E | O |
| ATOM | 10194 | N | MET | E | 725 | −14.120 | 63.484 | 26.955 | 1.00 | 8.43 | E | N |
| ATOM | 10195 | CA | MET | E | 725 | −13.686 | 62.195 | 26.414 | 1.00 | 11.33 | E | C |
| ATOM | 10196 | CB | MET | E | 725 | −14.867 | 61.453 | 25.787 | 1.00 | 8.10 | E | C |
| ATOM | 10197 | CG | MET | E | 725 | −15.940 | 61.031 | 26.774 | 1.00 | 8.21 | E | C |
| ATOM | 10198 | SD | MET | E | 725 | −15.400 | 59.749 | 27.938 | 1.00 | 11.31 | E | S |
| ATOM | 10199 | CE | MET | E | 725 | −14.858 | 58.473 | 26.855 | 1.00 | 7.47 | E | C |
| ATOM | 10200 | C | MET | E | 725 | −12.585 | 62.388 | 25.359 | 1.00 | 11.83 | E | C |
| ATOM | 10201 | O | MET | E | 725 | −11.581 | 61.670 | 25.358 | 1.00 | 13.56 | E | O |
| ATOM | 10202 | N | ALA | E | 726 | −12.771 | 63.363 | 24.473 | 1.00 | 11.97 | E | N |
| ATOM | 10203 | CA | ALA | E | 726 | −11.787 | 63.627 | 23.430 | 1.00 | 11.57 | E | C |
| ATOM | 10204 | CB | ALA | E | 726 | −12.319 | 64.668 | 22.447 | 1.00 | 12.94 | E | C |
| ATOM | 10205 | C | ALA | E | 726 | −10.482 | 64.102 | 24.036 | 1.00 | 11.69 | E | C |
| ATOM | 10206 | O | ALA | E | 726 | −9.401 | 63.678 | 23.623 | 1.00 | 13.24 | E | O |
| ATOM | 10207 | N | TYR | E | 727 | −10.574 | 64.989 | 25.020 | 1.00 | 11.58 | E | N |
| ATOM | 10208 | CA | TYR | E | 727 | −9.370 | 65.486 | 25.664 | 1.00 | 9.89 | E | C |
| ATOM | 10209 | CB | TYR | E | 727 | −9.717 | 66.508 | 26.744 | 1.00 | 9.77 | E | C |
| ATOM | 10210 | CG | TYR | E | 727 | −8.520 | 66.874 | 27.588 | 1.00 | 9.00 | E | C |
| ATOM | 10211 | CD1 | TYR | E | 727 | −8.277 | 66.242 | 28.804 | 1.00 | 8.39 | E | C |
| ATOM | 10212 | CE1 | TYR | E | 727 | −7.147 | 66.551 | 29.567 | 1.00 | 9.23 | E | C |
| ATOM | 10213 | CD2 | TYR | E | 727 | −7.604 | 67.828 | 27.151 | 1.00 | 9.12 | E | C |
| ATOM | 10214 | CE2 | TYR | E | 727 | −6.468 | 68.144 | 27.907 | 1.00 | 7.45 | E | C |
| ATOM | 10215 | CZ | TYR | E | 727 | −6.250 | 67.500 | 29.110 | 1.00 | 10.01 | E | C |
| ATOM | 10216 | OH | TYR | E | 727 | −5.138 | 67.797 | 29.858 | 1.00 | 11.50 | E | O |
| ATOM | 10217 | C | TYR | E | 727 | −8.590 | 64.332 | 26.291 | 1.00 | 11.57 | E | C |
| ATOM | 10218 | O | TYR | E | 727 | −7.397 | 64.180 | 26.052 | 1.00 | 11.40 | E | O |
| ATOM | 10219 | N | ARG | E | 728 | −9.262 | 63.520 | 27.099 | 1.00 | 11.14 | E | N |
| ATOM | 10220 | CA | ARG | E | 728 | −8.599 | 62.389 | 27.742 | 1.00 | 12.55 | E | C |
| ATOM | 10221 | CB | ARG | E | 728 | −9.607 | 61.547 | 28.541 | 1.00 | 10.30 | E | C |
| ATOM | 10222 | CG | ARG | E | 728 | −10.220 | 62.258 | 29.731 | 1.00 | 11.86 | E | C |
| ATOM | 10223 | CD | ARG | E | 728 | −9.172 | 62.595 | 30.772 | 1.00 | 8.87 | E | C |
| ATOM | 10224 | NE | ARG | E | 728 | −9.778 | 63.154 | 31.975 | 1.00 | 9.16 | E | N |
| ATOM | 10225 | CZ | ARG | E | 728 | −9.100 | 63.780 | 32.928 | 1.00 | 8.19 | E | C |
| ATOM | 10226 | NH1 | ARG | E | 728 | −7.790 | 63.927 | 32.816 | 1.00 | 7.90 | E | N |
| ATOM | 10227 | NH2 | ARG | E | 728 | −9.730 | 64.255 | 33.995 | 1.00 | 8.24 | E | N |
| ATOM | 10228 | C | ARG | E | 728 | −7.945 | 61.496 | 26.705 | 1.00 | 13.02 | E | C |
| ATOM | 10229 | O | ARG | E | 728 | −6.778 | 61.126 | 26.826 | 1.00 | 16.56 | E | O |
| ATOM | 10230 | N | TYR | E | 729 | −8.708 | 61.148 | 25.676 | 1.00 | 14.79 | E | N |
| ATOM | 10231 | CA | TYR | E | 729 | −8.214 | 60.261 | 24.636 | 1.00 | 9.93 | E | C |
| ATOM | 10232 | CB | TYR | E | 729 | −9.320 | 60.005 | 23.629 | 1.00 | 14.90 | E | C |
| ATOM | 10233 | CG | TYR | E | 729 | −9.029 | 58.866 | 22.687 | 1.00 | 21.80 | E | C |
| ATOM | 10234 | CD1 | TYR | E | 729 | −8.606 | 57.624 | 23.168 | 1.00 | 18.00 | E | C |
| ATOM | 10235 | CE1 | TYR | E | 729 | −8.330 | 56.576 | 22.289 | 1.00 | 21.45 | E | C |
| ATOM | 10236 | CD2 | TYR | E | 729 | −9.171 | 59.032 | 21.300 | 1.00 | 21.35 | E | C |
| ATOM | 10237 | CE2 | TYR | E | 729 | −8.898 | 57.995 | 20.424 | 1.00 | 22.88 | E | C |
| ATOM | 10238 | CZ | TYR | E | 729 | −8.480 | 56.773 | 20.919 | 1.00 | 23.09 | E | C |
| ATOM | 10239 | OH | TYR | E | 729 | −8.221 | 55.753 | 20.034 | 1.00 | 27.10 | E | O |
| ATOM | 10240 | C | TYR | E | 729 | −6.981 | 60.786 | 23.929 | 1.00 | 10.79 | E | C |
| ATOM | 10241 | O | TYR | E | 729 | −5.979 | 60.089 | 23.822 | 1.00 | 12.40 | E | O |
| ATOM | 10242 | N | GLU | E | 730 | −7.050 | 62.021 | 23.447 | 1.00 | 11.41 | E | N |
| ATOM | 10243 | CA | GLU | E | 730 | −5.927 | 62.614 | 22.731 | 1.00 | 10.75 | E | C |
| ATOM | 10244 | CB | GLU | E | 730 | −6.307 | 63.988 | 22.186 | 1.00 | 8.20 | E | C |
| ATOM | 10245 | CG | GLU | E | 730 | −7.560 | 63.981 | 21.338 | 1.00 | 9.42 | E | C |
| ATOM | 10246 | CD | GLU | E | 730 | −8.043 | 65.371 | 21.017 | 1.00 | 14.44 | E | C |
| ATOM | 10247 | OE1 | GLU | E | 730 | −9.158 | 65.501 | 20.476 | 1.00 | 21.34 | E | O |
| ATOM | 10248 | OE2 | GLU | E | 730 | −7.313 | 66.340 | 21.304 | 1.00 | 19.08 | E | O |
| ATOM | 10249 | C | GLU | E | 730 | −4.666 | 62.737 | 23.570 | 1.00 | 13.04 | E | C |
| ATOM | 10250 | O | GLU | E | 730 | −3.564 | 62.440 | 23.085 | 1.00 | 12.36 | E | O |
| ATOM | 10251 | N | THR | E | 731 | −4.799 | 63.163 | 24.827 | 1.00 | 13.98 | E | N |
| ATOM | 10252 | CA | THR | E | 731 | −3.602 | 63.304 | 25.637 | 1.00 | 11.77 | E | C |
| ATOM | 10253 | CB | THR | E | 731 | −3.829 | 64.250 | 26.851 | 1.00 | 13.77 | E | C |
| ATOM | 10254 | OG1 | THR | E | 731 | −3.770 | 63.511 | 28.069 | 1.00 | 17.90 | E | O |
| ATOM | 10255 | CG2 | THR | E | 731 | −5.143 | 64.965 | 26.738 | 1.00 | 6.19 | E | C |
| ATOM | 10256 | C | THR | E | 731 | −3.035 | 61.948 | 26.057 | 1.00 | 10.62 | E | C |
| ATOM | 10257 | O | THR | E | 731 | −1.836 | 61.826 | 26.310 | 1.00 | 12.56 | E | O |
| ATOM | 10258 | N | TRP | E | 732 | −3.877 | 60.919 | 26.092 | 1.00 | 9.32 | E | N |
| ATOM | 10259 | CA | TRP | E | 732 | −3.400 | 59.582 | 26.436 | 1.00 | 9.16 | E | C |
| ATOM | 10260 | CB | TRP | E | 732 | −4.577 | 58.659 | 26.760 | 1.00 | 6.43 | E | C |
| ATOM | 10261 | CG | TRP | E | 732 | −4.190 | 57.236 | 27.101 | 1.00 | 7.18 | E | C |
| ATOM | 10262 | CD2 | TRP | E | 732 | −5.027 | 56.072 | 26.998 | 1.00 | 6.20 | E | C |
| ATOM | 10263 | CE2 | TRP | E | 732 | −4.265 | 54.965 | 27.439 | 1.00 | 6.38 | E | C |
| ATOM | 10264 | CE3 | TRP | E | 732 | −6.350 | 55.859 | 26.577 | 1.00 | 10.94 | E | C |
| ATOM | 10265 | CD1 | TRP | E | 732 | −2.988 | 56.799 | 27.585 | 1.00 | 8.15 | E | C |
| ATOM | 10266 | NE1 | TRP | E | 732 | −3.025 | 55.433 | 27.793 | 1.00 | 9.49 | E | N |
| ATOM | 10267 | CZ2 | TRP | E | 732 | −4.779 | 53.659 | 27.470 | 1.00 | 6.68 | E | C |
| ATOM | 10268 | CZ3 | TRP | E | 732 | −6.866 | 54.550 | 26.613 | 1.00 | 11.96 | E | C |
| ATOM | 10269 | CH2 | TRP | E | 732 | −6.075 | 53.472 | 27.057 | 1.00 | 6.95 | E | C |
| ATOM | 10270 | C | TRP | E | 732 | −2.617 | 59.035 | 25.239 | 1.00 | 11.27 | E | C |
| ATOM | 10271 | O | TRP | E | 732 | −1.527 | 58.481 | 25.393 | 1.00 | 14.08 | E | O |
| ATOM | 10272 | N | CYS | E | 733 | −3.172 | 59.198 | 24.042 | 1.00 | 12.91 | E | N |
| ATOM | 10273 | CA | CYS | E | 733 | −2.511 | 58.726 | 22.823 | 1.00 | 15.09 | E | C |
| ATOM | 10274 | CB | CYS | E | 733 | −3.414 | 58.958 | 21.608 | 1.00 | 14.40 | E | C |
| ATOM | 10275 | SG | CYS | E | 733 | −4.753 | 57.753 | 21.465 | 1.00 | 19.69 | E | S |
| ATOM | 10276 | C | CYS | E | 733 | −1.187 | 59.449 | 22.613 | 1.00 | 14.02 | E | C |
| ATOM | 10277 | O | CYS | E | 733 | −0.183 | 58.848 | 22.236 | 1.00 | 14.85 | E | O |
| ATOM | 10278 | N | TYR | E | 734 | −1.189 | 60.750 | 22.864 | 1.00 | 15.32 | E | N |
| ATOM | 10279 | CA | TYR | E | 734 | 0.009 | 61.551 | 22.694 | 1.00 | 15.27 | E | C |
| ATOM | 10280 | CB | TYR | E | 734 | −0.293 | 63.006 | 23.059 | 1.00 | 16.78 | E | C |
| ATOM | 10281 | CG | TYR | E | 734 | 0.804 | 63.985 | 22.692 | 1.00 | 18.85 | E | C |
| ATOM | 10282 | CD1 | TYR | E | 734 | 0.766 | 64.692 | 21.487 | 1.00 | 17.65 | E | C |
| ATOM | 10283 | CE1 | TYR | E | 734 | 1.758 | 65.617 | 21.161 | 1.00 | 18.62 | E | C |
| ATOM | 10284 | CD2 | TYR | E | 734 | 1.865 | 64.224 | 23.560 | 1.00 | 20.52 | E | C |
| ATOM | 10285 | CE2 | TYR | E | 734 | 2.863 | 65.147 | 23.243 | 1.00 | 22.80 | E | C |
| ATOM | 10286 | CZ | TYR | E | 734 | 2.802 | 65.840 | 22.046 | 1.00 | 22.99 | E | C |
| ATOM | 10287 | OH | TYR | E | 734 | 3.779 | 66.767 | 21.756 | 1.00 | 25.70 | E | O |
| ATOM | 10288 | C | TYR | E | 734 | 1.181 | 61.034 | 23.528 | 1.00 | 16.99 | E | C |
| ATOM | 10289 | O | TYR | E | 734 | 2.320 | 60.990 | 23.056 | 1.00 | 19.99 | E | O |
| ATOM | 10290 | N | GLU | E | 735 | 0.910 | 60.637 | 24.769 | 1.00 | 16.16 | E | N |
| ATOM | 10291 | CA | GLU | E | 735 | 1.970 | 60.145 | 25.642 | 1.00 | 12.91 | E | C |
| ATOM | 10292 | CB | GLU | E | 735 | 1.444 | 59.975 | 27.073 | 1.00 | 16.97 | E | C |
| ATOM | 10293 | CG | GLU | E | 735 | 1.092 | 61.285 | 27.783 | 1.00 | 13.40 | E | C |
| ATOM | 10294 | CD | GLU | E | 735 | 2.263 | 62.253 | 27.875 | 1.00 | 14.63 | E | C |
| ATOM | 10295 | OE1 | GLU | E | 735 | 3.365 | 61.840 | 28.304 | 1.00 | 14.81 | E | O |
| ATOM | 10296 | OE2 | GLU | E | 735 | 2.078 | 63.440 | 27.522 | 1.00 | 17.34 | E | O |
| ATOM | 10297 | C | GLU | E | 735 | 2.542 | 58.827 | 25.148 | 1.00 | 13.03 | E | C |
| ATOM | 10298 | O | GLU | E | 735 | 3.759 | 58.633 | 25.129 | 1.00 | 14.41 | E | O |
| ATOM | 10299 | N | LEU | E | 736 | 1.665 | 57.913 | 24.756 | 1.00 | 13.24 | E | N |
| ATOM | 10300 | CA | LEU | E | 736 | 2.103 | 56.615 | 24.256 | 1.00 | 14.86 | E | C |
| ATOM | 10301 | CB | LEU | E | 736 | 0.895 | 55.736 | 23.941 | 1.00 | 11.83 | E | C |
| ATOM | 10302 | CG | LEU | E | 736 | 0.132 | 55.228 | 25.162 | 1.00 | 11.58 | E | C |
| ATOM | 10303 | CD1 | LEU | E | 736 | −1.285 | 54.831 | 24.759 | 1.00 | 6.38 | E | C |
| ATOM | 10304 | CD2 | LEU | E | 736 | 0.892 | 54.059 | 25.780 | 1.00 | 8.24 | E | C |
| ATOM | 10305 | C | LEU | E | 736 | 2.947 | 56.790 | 23.004 | 1.00 | 15.91 | E | C |
| ATOM | 10306 | O | LEU | E | 736 | 3.977 | 56.134 | 22.828 | 1.00 | 18.22 | E | O |
| ATOM | 10307 | N | ASN | E | 737 | 2.509 | 57.692 | 22.138 | 1.00 | 16.91 | E | N |
| ATOM | 10308 | CA | ASN | E | 737 | 3.214 | 57.958 | 20.895 | 1.00 | 19.52 | E | C |
| ATOM | 10309 | CB | ASN | E | 737 | 2.426 | 58.965 | 20.065 | 1.00 | 18.10 | E | C |
| ATOM | 10310 | CG | ASN | E | 737 | 2.964 | 59.100 | 18.676 | 1.00 | 20.85 | E | C |
| ATOM | 10311 | OD1 | ASN | E | 737 | 3.089 | 58.118 | 17.954 | 1.00 | 27.73 | E | O |
| ATOM | 10312 | ND2 | ASN | E | 737 | 3.296 | 60.320 | 18.287 | 1.00 | 23.12 | E | N |
| ATOM | 10313 | C | ASN | E | 737 | 4.638 | 58.464 | 21.107 | 1.00 | 20.63 | E | C |
| ATOM | 10314 | O | ASN | E | 737 | 5.542 | 58.139 | 20.332 | 1.00 | 22.68 | E | O |
| ATOM | 10315 | N | LEU | E | 738 | 4.843 | 59.260 | 22.151 | 1.00 | 17.98 | E | N |
| ATOM | 10316 | CA | LEU | E | 738 | 6.170 | 59.796 | 22.430 | 1.00 | 18.12 | E | C |
| ATOM | 10317 | CB | LEU | E | 738 | 6.154 | 60.633 | 23.710 | 1.00 | 16.25 | E | C |
| ATOM | 10318 | CG | LEU | E | 738 | 5.473 | 62.000 | 23.607 | 1.00 | 17.59 | E | C |
| ATOM | 10319 | CD1 | LEU | E | 738 | 5.370 | 62.633 | 24.988 | 1.00 | 12.29 | E | C |
| ATOM | 10320 | CD2 | LEU | E | 738 | 6.270 | 62.895 | 22.670 | 1.00 | 12.70 | E | C |
| ATOM | 10321 | C | LEU | E | 738 | 7.168 | 58.661 | 22.582 | 1.00 | 19.29 | E | C |
| ATOM | 10322 | O | LEU | E | 738 | 8.333 | 58.786 | 22.208 | 1.00 | 21.13 | E | O |
| ATOM | 10323 | N | ILE | E | 739 | 6.699 | 57.549 | 23.132 | 1.00 | 19.03 | E | N |
| ATOM | 10324 | CA | ILE | E | 739 | 7.545 | 56.389 | 23.338 | 1.00 | 19.77 | E | C |
| ATOM | 10325 | CB | ILE | E | 739 | 6.893 | 55.404 | 24.326 | 1.00 | 20.10 | E | C |
| ATOM | 10326 | CG2 | ILE | E | 739 | 7.749 | 54.145 | 24.454 | 1.00 | 19.10 | E | C |
| ATOM | 10327 | CG1 | ILE | E | 739 | 6.747 | 56.075 | 25.695 | 1.00 | 20.94 | E | C |
| ATOM | 10328 | CD1 | ILE | E | 739 | 5.718 | 55.425 | 26.594 | 1.00 | 23.15 | E | C |
| ATOM | 10329 | C | ILE | E | 739 | 7.820 | 55.675 | 22.021 | 1.00 | 19.72 | E | C |
| ATOM | 10330 | O | ILE | E | 739 | 8.954 | 55.281 | 21.746 | 1.00 | 19.13 | E | O |
| ATOM | 10331 | N | ALA | E | 740 | 6.782 | 55.512 | 21.210 | 1.00 | 19.95 | E | N |
| ATOM | 10332 | CA | ALA | E | 740 | 6.922 | 54.844 | 19.921 | 1.00 | 21.51 | E | C |
| ATOM | 10333 | CB | ALA | E | 740 | 5.572 | 54.784 | 19.212 | 1.00 | 18.77 | E | C |
| ATOM | 10334 | C | ALA | E | 740 | 7.936 | 55.586 | 19.058 | 1.00 | 20.79 | E | C |
| ATOM | 10335 | O | ALA | E | 740 | 8.777 | 54.971 | 18.407 | 1.00 | 18.54 | E | O |
| ATOM | 10336 | N | GLU | E | 741 | 7.853 | 56.913 | 19.064 | 1.00 | 22.16 | E | N |
| ATOM | 10337 | CA | GLU | E | 741 | 8.761 | 57.745 | 18.282 | 1.00 | 22.79 | E | C |
| ATOM | 10338 | CB | GLU | E | 741 | 8.339 | 59.210 | 18.370 | 1.00 | 22.17 | E | C |
| ATOM | 10339 | CG | GLU | E | 741 | 6.932 | 59.476 | 17.884 | 1.00 | 30.33 | E | C |
| ATOM | 10340 | CD | GLU | E | 741 | 6.829 | 59.529 | 16.372 | 1.00 | 32.52 | E | C |
| ATOM | 10341 | OE1 | GLU | E | 741 | 6.054 | 58.734 | 15.795 | 1.00 | 33.04 | E | O |
| ATOM | 10342 | OE2 | GLU | E | 741 | 7.522 | 60.368 | 15.760 | 1.00 | 34.24 | E | O |
| ATOM | 10343 | C | GLU | E | 741 | 10.209 | 57.611 | 18.747 | 1.00 | 23.40 | E | C |
| ATOM | 10344 | O | GLU | E | 741 | 11.129 | 57.622 | 17.932 | 1.00 | 23.65 | E | O |
| ATOM | 10345 | N | GLY | E | 742 | 10.410 | 57.493 | 20.055 | 1.00 | 23.00 | E | N |
| ATOM | 10346 | CA | GLY | E | 742 | 11.755 | 57.364 | 20.581 | 1.00 | 24.49 | E | C |
| ATOM | 10347 | C | GLY | E | 742 | 12.408 | 56.061 | 20.165 | 1.00 | 27.77 | E | C |
| ATOM | 10348 | O | GLY | E | 742 | 13.625 | 55.898 | 20.278 | 1.00 | 29.36 | E | O |
| ATOM | 10349 | N | LEU | E | 743 | 11.595 | 55.131 | 19.676 | 1.00 | 29.34 | E | N |
| ATOM | 10350 | CA | LEU | E | 743 | 12.069 | 53.822 | 19.243 | 1.00 | 30.18 | E | C |
| ATOM | 10351 | CB | LEU | E | 743 | 11.186 | 52.727 | 19.849 | 1.00 | 27.96 | E | C |
| ATOM | 10352 | CG | LEU | E | 743 | 11.547 | 52.034 | 21.172 | 1.00 | 28.83 | E | C |
| ATOM | 10353 | CD1 | LEU | E | 743 | 12.618 | 52.797 | 21.928 | 1.00 | 26.80 | E | C |
| ATOM | 10354 | CD2 | LEU | E | 743 | 10.282 | 51.911 | 22.012 | 1.00 | 25.80 | E | C |
| ATOM | 10355 | C | LEU | E | 743 | 12.040 | 53.693 | 17.721 | 1.00 | 32.97 | E | C |
| ATOM | 10356 | O | LEU | E | 743 | 12.574 | 52.732 | 17.166 | 1.00 | 34.89 | E | O |
| ATOM | 10357 | N | LYS | E | 744 | 11.409 | 54.657 | 17.054 | 1.00 | 35.58 | E | N |
| ATOM | 10358 | CA | LYS | E | 744 | 11.279 | 54.653 | 15.595 | 1.00 | 38.24 | E | C |
| ATOM | 10359 | CB | LYS | E | 744 | 10.535 | 55.912 | 15.133 | 1.00 | 34.62 | E | C |
| ATOM | 10360 | CG | LYS | E | 744 | 9.183 | 55.644 | 14.506 | 1.00 | 33.22 | E | C |
| ATOM | 10361 | CD | LYS | E | 744 | 9.037 | 56.383 | 13.193 | 1.00 | 35.72 | E | C |
| ATOM | 10362 | CE | LYS | E | 744 | 7.785 | 57.245 | 13.172 | 1.00 | 39.12 | E | C |
| ATOM | 10363 | NZ | LYS | E | 744 | 7.804 | 58.217 | 12.040 | 1.00 | 40.75 | E | N |
| ATOM | 10364 | C | LYS | E | 744 | 12.609 | 54.562 | 14.848 | 1.00 | 42.42 | E | C |
| ATOM | 10365 | O | LYS | E | 744 | 13.655 | 54.976 | 15.357 | 1.00 | 42.26 | E | O |
| ATOM | 10366 | N | SER | E | 745 | 12.548 | 54.019 | 13.632 | 1.00 | 47.33 | E | N |
| ATOM | 10367 | CA | SER | E | 745 | 13.716 | 53.871 | 12.765 | 1.00 | 52.15 | E | C |
| ATOM | 10368 | CB | SER | E | 745 | 14.818 | 53.083 | 13.480 | 1.00 | 53.25 | E | C |
| ATOM | 10369 | OG | SER | E | 745 | 16.048 | 53.785 | 13.420 | 1.00 | 55.45 | E | O |
| ATOM | 10370 | C | SER | E | 745 | 13.346 | 53.170 | 11.455 | 1.00 | 54.83 | E | C |
| ATOM | 10371 | O | SER | E | 745 | 13.704 | 51.979 | 11.296 | 1.00 | 57.07 | E | O |
| ATOM | 10372 | OT | SER | E | 745 | 12.700 | 53.822 | 10.602 | 1.00 | 56.51 | E | O |
| ATOM | 10373 | ZN | ZN | Y | 895 | 26.296 | 64.563 | 54.507 | 1.00 | 14.06 | Y | |
| ATOM | 10374 | ZN | ZN | Z | 896 | −10.467 | 48.570 | 52.381 | 1.00 | 14.46 | Z | |
| ATOM | 1 | C1 | COF | H | 1 | 28.760 | 61.746 | 50.260 | 1.00 | 20.00 | | |
| ATOM | 2 | O1 | COF | H | 1 | 30.110 | 62.108 | 50.530 | 1.00 | 20.00 | | |
| ATOM | 3 | C5 | COF | H | 1 | 30.946 | 61.172 | 49.775 | 1.00 | 20.00 | | |
| ATOM | 4 | C8 | COF | H | 1 | 32.108 | 61.907 | 49.222 | 1.00 | 20.00 | | |
| ATOM | 5 | O6 | COF | H | 1 | 32.257 | 63.157 | 49.888 | 1.00 | 20.00 | | |
| ATOM | 6 | C4 | COF | H | 1 | 30.025 | 60.529 | 48.719 | 1.00 | 20.00 | | |
| ATOM | 7 | O5 | COF | H | 1 | 29.750 | 59.182 | 49.110 | 1.00 | 20.00 | | |
| ATOM | 8 | C3 | COF | H | 1 | 28.754 | 61.392 | 48.766 | 1.00 | 20.00 | | |
| ATOM | 9 | O4 | COF | H | 1 | 27.594 | 60.691 | 48.387 | 1.00 | 20.00 | | |
| ATOM | 10 | N2 | COF | H | 1 | 27.905 | 62.853 | 50.641 | 1.00 | 20.00 | | |
| ATOM | 11 | C6 | COF | H | 1 | 26.618 | 62.735 | 51.155 | 1.00 | 20.00 | | |
| ATOM | 12 | N3 | COF | H | 1 | 26.073 | 61.486 | 51.359 | 1.00 | 20.00 | | |
| ATOM | 13 | C7 | COF | H | 1 | 24.839 | 61.344 | 51.737 | 1.00 | 20.00 | | |
| ATOM | 14 | N4 | COF | H | 1 | 23.872 | 62.232 | 51.951 | 1.00 | 20.00 | | |
| ATOM | 15 | C9 | COF | H | 1 | 23.783 | 63.607 | 51.445 | 1.00 | 20.00 | | |
| ATOM | 16 | C10 | COF | H | 1 | 24.915 | 64.483 | 51.937 | 1.00 | 20.00 | | |
| ATOM | 17 | O7 | COF | H | 1 | 24.920 | 64.561 | 53.378 | 1.00 | 20.00 | | |
| ATOM | 18 | C11 | COF | H | 1 | 26.216 | 64.015 | 51.399 | 1.00 | 20.00 | | |
| ATOM | 19 | N1 | COF | H | 1 | 27.226 | 64.913 | 51.012 | 1.00 | 20.00 | | |
| ATOM | 20 | C2 | COF | H | 1 | 28.214 | 64.183 | 50.560 | 1.00 | 20.00 | | |
| ATOM | 1 | C1 | COF | J | 1 | −14.579 | 48.848 | 55.225 | 1.00 | 20.00 | C | C |
| ATOM | 2 | O1 | COF | J | 1 | −14.156 | 48.925 | 56.582 | 1.00 | 20.00 | C | O |
| ATOM | 3 | C5 | COF | J | 1 | −15.140 | 49.761 | 57.273 | 1.00 | 20.00 | C | C |
| ATOM | 4 | C8 | COF | J | 1 | −15.382 | 49.199 | 58.623 | 1.00 | 20.00 | C | C |
| ATOM | 5 | O6 | COF | J | 1 | −14.344 | 48.286 | 58.965 | 1.00 | 20.00 | C | O |
| ATOM | 6 | C4 | COF | J | 1 | −16.381 | 49.808 | 56.360 | 1.00 | 20.00 | C | C |
| ATOM | 7 | O5 | COF | J | 1 | −16.456 | 51.101 | 55.755 | 1.00 | 20.00 | C | O |
| ATOM | 8 | C3 | COF | J | 1 | −16.107 | 48.719 | 55.311 | 1.00 | 20.00 | C | C |
| ATOM | 9 | O4 | COF | J | 1 | −16.735 | 48.967 | 54.076 | 1.00 | 20.00 | C | O |
| ATOM | 10 | N2 | COF | J | 1 | −13.895 | 47.737 | 54.595 | 1.00 | 20.00 | C | N |
| ATOM | 11 | C6 | COF | J | 1 | −13.495 | 47.689 | 53.264 | 1.00 | 20.00 | C | C |
| ATOM | 12 | N3 | COF | J | 1 | −13.725 | 48.769 | 52.439 | 1.00 | 20.00 | C | N |
| ATOM | 13 | C7 | COF | J | 1 | −13.460 | 48.714 | 51.170 | 1.00 | 20.00 | C | C |
| ATOM | 14 | N4 | COF | J | 1 | −13.008 | 47.726 | 50.402 | 1.00 | 20.00 | C | N |
| ATOM | 15 | C9 | COF | J | 1 | −13.047 | 46.284 | 50.673 | 1.00 | 20.00 | C | C |
| ATOM | 16 | C10 | COF | J | 1 | −12.257 | 45.902 | 51.906 | 1.00 | 20.00 | C | C |
| ATOM | 17 | O7 | COF | J | 1 | −10.868 | 46.270 | 51.765 | 1.00 | 20.00 | C | O |
| ATOM | 18 | C11 | COF | J | 1 | −12.867 | 46.486 | 53.126 | 1.00 | 20.00 | C | C |
| ATOM | 19 | N1 | COF | J | 1 | −12.906 | 45.787 | 54.345 | 1.00 | 20.00 | C | N |
| ATOM | 20 | C2 | COF | J | 1 | −13.531 | 46.562 | 55.194 | 1.00 | 20.00 | C | C |
| END | | | | | | | | | | | | |

TABLE 4
Atomic coordinates for AMPDA with UK-384, 858

| | |
|---|---|
| REMARK | xplor input |
| CRYST1 | 149.265 149.265 158.595 90.00 90.00 90.00 P42212 |
| SCALE1 | 0.00670 0.00000 0.00000 0.00000 |
| SCALE2 | 0.00000 0.00670 0.00000 0.00000 |
| SCALE3 | 0.00000 0.00000 0.00631 0.00000 |
| REMARK | FILENAME = “brefinement.pdb” |
| REMARK | r = 0.260115 free_r = 0.284984 |
| REMARK | DATE: 24-May-00 12:17:44 created by user: chrisp |

| | | | | | | | | | | | | |
|---|---|---|---|---|---|---|---|---|---|---|---|---|
| ATOM | 1 | CB | SER | A | 106 | 17.453 | 72.613 | 93.123 | 1.00 | 43.12 | A | C |
| ATOM | 2 | OG | SER | A | 106 | 18.525 | 72.989 | 92.276 | 1.00 | 45.52 | A | O |
| ATOM | 3 | C | SER | A | 106 | 18.676 | 74.346 | 94.464 | 1.00 | 41.98 | A | C |
| ATOM | 4 | O | SER | A | 106 | 18.496 | 75.457 | 93.960 | 1.00 | 43.03 | A | O |
| ATOM | 5 | N | SER | A | 106 | 16.253 | 73.936 | 94.839 | 1.00 | 42.44 | A | N |
| ATOM | 6 | CA | SER | A | 106 | 17.556 | 73.302 | 94.487 | 1.00 | 42.11 | A | C |
| ATOM | 7 | N | PRO | A | 107 | 19.855 | 73.993 | 95.002 | 1.00 | 40.34 | A | N |
| ATOM | 8 | CD | PRO | A | 107 | 20.187 | 72.686 | 95.597 | 1.00 | 39.37 | A | C |
| ATOM | 9 | CA | PRO | A | 107 | 20.997 | 74.913 | 95.041 | 1.00 | 39.23 | A | C |
| ATOM | 10 | CB | PRO | A | 107 | 22.075 | 74.126 | 95.793 | 1.00 | 37.41 | A | C |
| ATOM | 11 | CG | PRO | A | 107 | 21.366 | 73.001 | 96.452 | 1.00 | 37.90 | A | C |
| ATOM | 12 | C | PRO | A | 107 | 21.510 | 75.417 | 93.685 | 1.00 | 39.51 | A | C |
| ATOM | 13 | O | PRO | A | 107 | 22.098 | 76.498 | 93.605 | 1.00 | 39.91 | A | O |
| ATOM | 14 | N | THR | A | 108 | 21.284 | 74.647 | 92.624 | 1.00 | 38.48 | A | N |
| ATOM | 15 | CA | THR | A | 108 | 21.771 | 75.029 | 91.301 | 1.00 | 37.98 | A | C |
| ATOM | 16 | CB | THR | A | 108 | 21.867 | 73.789 | 90.369 | 1.00 | 37.59 | A | C |
| ATOM | 17 | OG1 | THR | A | 108 | 20.562 | 73.424 | 89.900 | 1.00 | 37.69 | A | O |
| ATOM | 18 | CG2 | THR | A | 108 | 22.481 | 72.612 | 91.116 | 1.00 | 37.90 | A | C |
| ATOM | 19 | C | THR | A | 108 | 20.985 | 76.131 | 90.579 | 1.00 | 37.49 | A | C |
| ATOM | 20 | O | THR | A | 108 | 21.329 | 76.497 | 89.452 | 1.00 | 38.09 | A | O |
| ATOM | 21 | N | TYR | A | 109 | 19.953 | 76.676 | 91.220 | 1.00 | 36.10 | A | N |
| ATOM | 22 | CA | TYR | A | 109 | 19.156 | 77.725 | 90.588 | 1.00 | 34.17 | A | C |
| ATOM | 23 | CB | TYR | A | 109 | 17.667 | 77.452 | 90.803 | 1.00 | 33.68 | A | C |
| ATOM | 24 | CG | TYR | A | 109 | 17.085 | 76.513 | 89.771 | 1.00 | 35.35 | A | C |
| ATOM | 25 | CD1 | TYR | A | 109 | 17.793 | 75.386 | 89.346 | 1.00 | 35.54 | A | C |
| ATOM | 26 | CE1 | TYR | A | 109 | 17.262 | 74.514 | 88.397 | 1.00 | 35.06 | A | C |
| ATOM | 27 | CD2 | TYR | A | 109 | 15.828 | 76.747 | 89.216 | 1.00 | 35.25 | A | C |
| ATOM | 28 | CE2 | TYR | A | 109 | 15.289 | 75.881 | 88.267 | 1.00 | 35.37 | A | C |
| ATOM | 29 | CZ | TYR | A | 109 | 16.009 | 74.768 | 87.864 | 1.00 | 35.12 | A | C |
| ATOM | 30 | OH | TYR | A | 109 | 15.463 | 73.902 | 86.944 | 1.00 | 36.34 | A | O |
| ATOM | 31 | C | TYR | A | 109 | 19.503 | 79.129 | 91.071 | 1.00 | 32.85 | A | C |
| ATOM | 32 | O | TYR | A | 109 | 18.808 | 80.093 | 90.747 | 1.00 | 32.02 | A | O |
| ATOM | 33 | N | GLN | A | 110 | 20.584 | 79.239 | 91.836 | 1.00 | 31.18 | A | N |
| ATOM | 34 | CA | GLN | A | 110 | 21.020 | 80.527 | 92.362 | 1.00 | 31.58 | A | C |
| ATOM | 35 | CB | GLN | A | 110 | 22.316 | 80.366 | 93.166 | 1.00 | 31.78 | A | C |
| ATOM | 36 | CG | GLN | A | 110 | 22.739 | 81.623 | 93.930 | 1.00 | 31.66 | A | C |
| ATOM | 37 | CD | GLN | A | 110 | 21.805 | 81.951 | 95.086 | 1.00 | 31.74 | A | C |
| ATOM | 38 | OE1 | GLN | A | 110 | 20.846 | 81.219 | 95.350 | 1.00 | 31.54 | A | O |
| ATOM | 39 | NE2 | GLN | A | 110 | 22.080 | 83.056 | 95.781 | 1.00 | 29.00 | A | N |
| ATOM | 40 | C | GLN | A | 110 | 21.264 | 81.503 | 91.227 | 1.00 | 30.70 | A | C |
| ATOM | 41 | O | GLN | A | 110 | 21.270 | 82.723 | 91.420 | 1.00 | 31.16 | A | O |
| ATOM | 42 | N | THR | A | 111 | 21.460 | 80.955 | 90.035 | 1.00 | 29.44 | A | N |
| ATOM | 43 | CA | THR | A | 111 | 21.744 | 81.765 | 88.869 | 1.00 | 27.54 | A | C |
| ATOM | 44 | CB | THR | A | 111 | 23.039 | 81.265 | 88.204 | 1.00 | 27.34 | A | C |
| ATOM | 45 | OG1 | THR | A | 111 | 23.548 | 82.284 | 87.345 | 1.00 | 32.97 | A | O |
| ATOM | 46 | CG2 | THR | A | 111 | 22.788 | 80.003 | 87.406 | 1.00 | 23.37 | A | C |
| ATOM | 47 | C | THR | A | 111 | 20.605 | 81.800 | 87.845 | 1.00 | 25.96 | A | C |
| ATOM | 48 | O | THR | A | 111 | 20.731 | 82.431 | 86.795 | 1.00 | 25.95 | A | O |
| ATOM | 49 | N | VAL | A | 112 | 19.493 | 81.138 | 88.167 | 1.00 | 23.22 | A | N |
| ATOM | 50 | CA | VAL | A | 112 | 18.326 | 81.078 | 87.283 | 1.00 | 19.66 | A | C |
| ATOM | 51 | CB | VAL | A | 112 | 17.671 | 79.684 | 87.324 | 1.00 | 15.21 | A | C |
| ATOM | 52 | CG1 | VAL | A | 112 | 16.493 | 79.635 | 86.368 | 1.00 | 13.25 | A | C |
| ATOM | 53 | CG2 | VAL | A | 112 | 18.690 | 78.623 | 86.995 | 1.00 | 14.22 | A | C |
| ATOM | 54 | C | VAL | A | 112 | 17.246 | 82.093 | 87.659 | 1.00 | 19.44 | A | C |
| ATOM | 55 | O | VAL | A | 112 | 16.682 | 82.025 | 88.744 | 1.00 | 20.43 | A | O |
| ATOM | 56 | N | PRO | A | 113 | 16.935 | 83.040 | 86.759 | 1.00 | 18.82 | A | N |
| ATOM | 57 | CD | PRO | A | 113 | 17.532 | 83.235 | 85.430 | 1.00 | 17.83 | A | C |
| ATOM | 58 | CA | PRO | A | 113 | 15.904 | 84.044 | 87.047 | 1.00 | 18.11 | A | C |
| ATOM | 59 | CB | PRO | A | 113 | 16.004 | 85.017 | 85.877 | 1.00 | 18.69 | A | C |
| ATOM | 60 | CG | PRO | A | 113 | 17.300 | 84.681 | 85.183 | 1.00 | 18.08 | A | C |
| ATOM | 61 | C | PRO | A | 113 | 14.504 | 83.434 | 87.144 | 1.00 | 20.59 | A | C |
| ATOM | 62 | O | PRO | A | 113 | 14.265 | 82.312 | 86.694 | 1.00 | 19.59 | A | O |
| ATOM | 63 | N | ASP | A | 114 | 13.580 | 84.174 | 87.745 | 1.00 | 22.07 | A | N |
| ATOM | 64 | CA | ASP | A | 114 | 12.210 | 83.703 | 87.871 | 1.00 | 23.17 | A | C |
| ATOM | 65 | CB | ASP | A | 114 | 11.388 | 84.645 | 88.755 | 1.00 | 26.56 | A | C |
| ATOM | 66 | CG | ASP | A | 114 | 11.725 | 84.525 | 90.228 | 1.00 | 30.50 | A | C |
| ATOM | 67 | OD1 | ASP | A | 114 | 11.874 | 83.387 | 90.727 | 1.00 | 32.52 | A | O |
| ATOM | 68 | OD2 | ASP | A | 114 | 11.835 | 85.582 | 90.889 | 1.00 | 32.44 | A | O |
| ATOM | 69 | C | ASP | A | 114 | 11.590 | 83.722 | 86.481 | 1.00 | 22.85 | A | C |
| ATOM | 70 | O | ASP | A | 114 | 12.001 | 84.505 | 85.627 | 1.00 | 24.29 | A | O |
| ATOM | 71 | N | PHE | A | 115 | 10.607 | 82.856 | 86.259 | 1.00 | 20.40 | A | N |
| ATOM | 72 | CA | PHE | A | 115 | 9.876 | 82.816 | 84.998 | 1.00 | 17.81 | A | C |
| ATOM | 73 | CB | PHE | A | 115 | 10.757 | 82.309 | 83.831 | 1.00 | 15.01 | A | C |
| ATOM | 74 | CG | PHE | A | 115 | 11.185 | 80.869 | 83.935 | 1.00 | 12.03 | A | C |
| ATOM | 75 | CD1 | PHE | A | 115 | 12.364 | 80.525 | 84.582 | 1.00 | 12.71 | A | C |
| ATOM | 76 | CD2 | PHE | A | 115 | 10.437 | 79.866 | 83.337 | 1.00 | 12.35 | A | C |
| ATOM | 77 | CE1 | PHE | A | 115 | 12.793 | 79.201 | 84.631 | 1.00 | 13.24 | A | C |
| ATOM | 78 | CE2 | PHE | A | 115 | 10.856 | 78.534 | 83.380 | 1.00 | 14.87 | A | C |
| ATOM | 79 | CZ | PHE | A | 115 | 12.038 | 78.201 | 84.030 | 1.00 | 12.54 | A | C |
| ATOM | 80 | C | PHE | A | 115 | 8.620 | 81.969 | 85.196 | 1.00 | 18.88 | A | C |
| ATOM | 81 | O | PHE | A | 115 | 8.567 | 81.112 | 86.090 | 1.00 | 17.41 | A | O |
| ATOM | 82 | N | GLN | A | 116 | 7.596 | 82.236 | 84.390 | 1.00 | 17.88 | A | N |
| ATOM | 83 | CA | GLN | A | 116 | 6.337 | 81.517 | 84.502 | 1.00 | 17.51 | A | C |
| ATOM | 84 | CB | GLN | A | 116 | 5.233 | 82.305 | 83.810 | 1.00 | 18.76 | A | C |
| ATOM | 85 | CG | GLN | A | 116 | 5.038 | 83.678 | 84.434 | 1.00 | 22.33 | A | C |
| ATOM | 86 | CD | GLN | A | 116 | 3.912 | 84.458 | 83.800 | 1.00 | 25.02 | A | C |
| ATOM | 87 | OE1 | GLN | A | 116 | 4.101 | 85.107 | 82.771 | 1.00 | 25.28 | A | O |
| ATOM | 88 | NE2 | GLN | A | 116 | 2.730 | 84.406 | 84.414 | 1.00 | 25.70 | A | N |
| ATOM | 89 | C | GLN | A | 116 | 6.414 | 80.110 | 83.950 | 1.00 | 17.07 | A | C |
| ATOM | 90 | O | GLN | A | 116 | 6.900 | 79.884 | 82.846 | 1.00 | 18.18 | A | O |
| ATOM | 91 | N | ARG | A | 117 | 5.932 | 79.158 | 84.736 | 1.00 | 17.06 | A | N |
| ATOM | 92 | CA | ARG | A | 117 | 5.959 | 77.772 | 84.329 | 1.00 | 17.71 | A | C |
| ATOM | 93 | CB | ARG | A | 117 | 6.650 | 76.933 | 85.399 | 1.00 | 17.01 | A | C |
| ATOM | 94 | CG | ARG | A | 117 | 8.155 | 77.135 | 85.433 | 1.00 | 19.15 | A | C |
| ATOM | 95 | CD | ARG | A | 117 | 8.705 | 76.788 | 86.798 | 1.00 | 20.98 | A | C |
| ATOM | 96 | NE | ARG | A | 117 | 10.160 | 76.669 | 86.799 | 1.00 | 21.96 | A | N |
| ATOM | 97 | CZ | ARG | A | 117 | 10.980 | 77.608 | 87.259 | 1.00 | 21.82 | A | C |
| ATOM | 98 | NH1 | ARG | A | 117 | 10.481 | 78.733 | 87.752 | 1.00 | 18.92 | A | N |
| ATOM | 99 | NH2 | ARG | A | 117 | 12.293 | 77.413 | 87.246 | 1.00 | 21.19 | A | N |
| ATOM | 100 | C | ARG | A | 117 | 4.566 | 77.247 | 84.084 | 1.00 | 18.75 | A | C |
| ATOM | 101 | O | ARG | A | 117 | 3.579 | 77.799 | 84.584 | 1.00 | 18.37 | A | O |
| ATOM | 102 | N | VAL | A | 118 | 4.480 | 76.184 | 83.296 | 1.00 | 18.74 | A | N |
| ATOM | 103 | CA | VAL | A | 118 | 3.190 | 75.590 | 83.017 | 1.00 | 21.07 | A | C |
| ATOM | 104 | CB | VAL | A | 118 | 2.958 | 75.389 | 81.486 | 1.00 | 21.53 | A | C |
| ATOM | 105 | CG1 | VAL | A | 118 | 4.236 | 75.645 | 80.720 | 1.00 | 22.68 | A | C |
| ATOM | 106 | CG2 | VAL | A | 118 | 2.417 | 73.991 | 81.203 | 1.00 | 19.94 | A | C |
| ATOM | 107 | C | VAL | A | 118 | 3.128 | 74.264 | 83.741 | 1.00 | 21.76 | A | C |
| ATOM | 108 | O | VAL | A | 118 | 4.000 | 73.419 | 83.576 | 1.00 | 24.19 | A | O |
| ATOM | 109 | N | GLN | A | 119 | 2.108 | 74.087 | 84.568 | 1.00 | 22.60 | A | N |
| ATOM | 110 | CA | GLN | A | 119 | 1.970 | 72.839 | 85.292 | 1.00 | 23.93 | A | C |
| ATOM | 111 | CB | GLN | A | 119 | 2.278 | 73.023 | 86.781 | 1.00 | 25.42 | A | C |
| ATOM | 112 | CG | GLN | A | 119 | 1.905 | 74.361 | 87.372 | 1.00 | 33.22 | A | C |
| ATOM | 113 | CD | GLN | A | 119 | 2.072 | 74.369 | 88.887 | 1.00 | 38.34 | A | C |
| ATOM | 114 | OE1 | GLN | A | 119 | 1.164 | 73.975 | 89.626 | 1.00 | 38.45 | A | O |
| ATOM | 115 | NE2 | GLN | A | 119 | 3.239 | 74.809 | 89.355 | 1.00 | 36.19 | A | N |
| ATOM | 116 | C | GLN | A | 119 | 0.589 | 72.252 | 85.110 | 1.00 | 22.72 | A | C |
| ATOM | 117 | O | GLN | A | 119 | −0.394 | 72.970 | 84.926 | 1.00 | 21.62 | A | O |
| ATOM | 118 | N | ILE | A | 120 | 0.540 | 70.928 | 85.146 | 1.00 | 21.37 | A | N |
| ATOM | 119 | CA | ILE | A | 120 | −0.688 | 70.180 | 84.973 | 1.00 | 20.11 | A | C |
| ATOM | 120 | CB | ILE | A | 120 | −0.478 | 69.028 | 83.968 | 1.00 | 16.83 | A | C |
| ATOM | 121 | CG2 | ILE | A | 120 | −1.798 | 68.364 | 83.650 | 1.00 | 14.93 | A | C |
| ATOM | 122 | CG1 | ILE | A | 120 | 0.216 | 69.559 | 82.709 | 1.00 | 15.64 | A | C |
| ATOM | 123 | CD1 | ILE | A | 120 | −0.446 | 70.785 | 82.093 | 1.00 | 16.03 | A | C |
| ATOM | 124 | C | ILE | A | 120 | −1.084 | 69.596 | 86.315 | 1.00 | 22.42 | A | C |
| ATOM | 125 | O | ILE | A | 120 | −0.258 | 69.002 | 87.004 | 1.00 | 22.69 | A | O |
| ATOM | 126 | N | THR | A | 121 | −2.348 | 69.772 | 86.680 | 1.00 | 25.71 | A | N |
| ATOM | 127 | CA | THR | A | 121 | −2.870 | 69.252 | 87.935 | 1.00 | 28.11 | A | C |
| ATOM | 128 | CB | THR | A | 121 | −3.811 | 70.262 | 88.599 | 1.00 | 27.51 | A | C |
| ATOM | 129 | OG1 | THR | A | 121 | −5.033 | 70.333 | 87.858 | 1.00 | 29.51 | A | O |
| ATOM | 130 | CG2 | THR | A | 121 | −3.175 | 71.634 | 88.638 | 1.00 | 28.70 | A | C |
| ATOM | 131 | C | THR | A | 121 | −3.643 | 67.970 | 87.655 | 1.00 | 30.61 | A | C |
| ATOM | 132 | O | THR | A | 121 | −4.013 | 67.705 | 86.515 | 1.00 | 31.64 | A | O |
| ATOM | 133 | N | GLY | A | 122 | −3.870 | 67.167 | 88.689 | 1.00 | 32.81 | A | N |
| ATOM | 134 | CA | GLY | A | 122 | −4.611 | 65.930 | 88.506 | 1.00 | 37.16 | A | C |
| ATOM | 135 | C | GLY | A | 122 | −3.761 | 64.694 | 88.271 | 1.00 | 40.41 | A | C |
| ATOM | 136 | O | GLY | A | 122 | −2.560 | 64.790 | 88.002 | 1.00 | 41.15 | A | O |
| ATOM | 137 | N | ASP | A | 123 | −4.401 | 63.529 | 88.375 | 1.00 | 43.33 | A | N |
| ATOM | 138 | CA | ASP | A | 123 | −3.740 | 62.239 | 88.182 | 1.00 | 46.02 | A | C |
| ATOM | 139 | CB | ASP | A | 123 | −4.521 | 61.129 | 88.892 | 1.00 | 49.81 | A | C |
| ATOM | 140 | CG | ASP | A | 123 | −4.566 | 61.314 | 90.399 | 1.00 | 53.68 | A | C |
| ATOM | 141 | OD1 | ASP | A | 123 | −3.494 | 61.545 | 91.003 | 1.00 | 55.04 | A | O |
| ATOM | 142 | OD2 | ASP | A | 123 | −5.675 | 61.224 | 90.978 | 1.00 | 56.30 | A | O |
| ATOM | 143 | C | ASP | A | 123 | −3.657 | 61.913 | 86.700 | 1.00 | 45.48 | A | C |
| ATOM | 144 | O | ASP | A | 123 | −4.626 | 62.103 | 85.965 | 1.00 | 46.84 | A | O |
| ATOM | 145 | N | TYR | A | 124 | −2.508 | 61.410 | 86.264 | 1.00 | 44.80 | A | N |
| ATOM | 146 | CA | TYR | A | 124 | −2.328 | 61.073 | 84.857 | 1.00 | 45.92 | A | C |
| ATOM | 147 | CB | TYR | A | 124 | −0.836 | 61.002 | 84.521 | 1.00 | 42.76 | A | C |
| ATOM | 148 | CG | TYR | A | 124 | −0.259 | 62.335 | 84.111 | 1.00 | 39.54 | A | C |
| ATOM | 149 | CD1 | TYR | A | 124 | 0.339 | 63.172 | 85.051 | 1.00 | 39.20 | A | C |
| ATOM | 150 | CE1 | TYR | A | 124 | 0.846 | 64.419 | 84.689 | 1.00 | 37.82 | A | C |
| ATOM | 151 | CD2 | TYR | A | 124 | −0.336 | 62.775 | 82.793 | 1.00 | 37.10 | A | C |
| ATOM | 152 | CE2 | TYR | A | 124 | 0.168 | 64.021 | 82.421 | 1.00 | 36.43 | A | C |
| ATOM | 153 | CZ | TYR | A | 124 | 0.757 | 64.838 | 83.374 | 1.00 | 35.72 | A | C |
| ATOM | 154 | OH | TYR | A | 124 | 1.253 | 66.072 | 83.020 | 1.00 | 33.78 | A | O |
| ATOM | 155 | C | TYR | A | 124 | −3.020 | 59.766 | 84.469 | 1.00 | 46.71 | A | C |
| ATOM | 156 | O | TYR | A | 124 | −2.610 | 58.699 | 84.975 | 1.00 | 48.42 | A | O |
| ATOM | 157 | OT | TYR | A | 124 | −3.973 | 59.831 | 83.660 | 1.00 | 48.02 | A | O |
| ATOM | 158 | CB | ASP | B | 132 | −2.865 | 49.114 | 79.287 | 1.00 | 54.68 | B | C |
| ATOM | 159 | CG | ASP | B | 132 | −2.872 | 49.637 | 77.856 | 1.00 | 56.72 | B | C |
| ATOM | 160 | OD1 | ASP | B | 132 | −2.864 | 50.876 | 77.676 | 1.00 | 56.22 | B | O |
| ATOM | 161 | OD2 | ASP | B | 132 | −2.889 | 48.810 | 76.914 | 1.00 | 57.96 | B | O |
| ATOM | 162 | C | ASP | B | 132 | −0.435 | 49.597 | 79.646 | 1.00 | 51.45 | B | C |
| ATOM | 163 | O | ASP | B | 132 | 0.555 | 49.473 | 78.922 | 1.00 | 50.84 | B | O |
| ATOM | 164 | N | ASP | B | 132 | −1.590 | 47.953 | 81.080 | 1.00 | 52.43 | B | N |
| ATOM | 165 | CA | ASP | B | 132 | −1.511 | 48.518 | 79.697 | 1.00 | 52.66 | B | C |
| ATOM | 166 | N | PHE | B | 133 | −0.640 | 50.658 | 80.420 | 1.00 | 50.20 | B | N |
| ATOM | 167 | CA | PHE | B | 133 | 0.316 | 51.754 | 80.484 | 1.00 | 47.84 | B | C |
| ATOM | 168 | CB | PHE | B | 133 | −0.240 | 52.891 | 81.348 | 1.00 | 46.26 | B | C |
| ATOM | 169 | CG | PHE | B | 133 | 0.754 | 53.983 | 81.631 | 1.00 | 45.48 | B | C |
| ATOM | 170 | CD1 | PHE | B | 133 | 0.906 | 54.480 | 82.922 | 1.00 | 43.53 | B | C |
| ATOM | 171 | CD2 | PHE | B | 133 | 1.543 | 54.512 | 80.606 | 1.00 | 44.77 | B | C |
| ATOM | 172 | CE1 | PHE | B | 133 | 1.827 | 55.489 | 83.195 | 1.00 | 42.52 | B | C |
| ATOM | 173 | CE2 | PHE | B | 133 | 2.468 | 55.522 | 80.864 | 1.00 | 44.35 | B | C |
| ATOM | 174 | CZ | PHE | B | 133 | 2.611 | 56.012 | 82.165 | 1.00 | 44.20 | B | C |
| ATOM | 175 | C | PHE | B | 133 | 1.593 | 51.204 | 81.104 | 1.00 | 47.69 | B | C |
| ATOM | 176 | O | PHE | B | 133 | 2.697 | 51.660 | 80.804 | 1.00 | 47.88 | B | O |
| ATOM | 177 | N | GLU | B | 134 | 1.427 | 50.211 | 81.970 | 1.00 | 46.68 | B | N |
| ATOM | 178 | CA | GLU | B | 134 | 2.552 | 49.581 | 82.640 | 1.00 | 45.74 | B | C |
| ATOM | 179 | CB | GLU | B | 134 | 2.045 | 48.537 | 83.636 | 1.00 | 47.75 | B | C |
| ATOM | 180 | CG | GLU | B | 134 | 2.829 | 48.503 | 84.940 | 1.00 | 51.78 | B | C |
| ATOM | 181 | CD | GLU | B | 134 | 3.195 | 47.093 | 85.369 | 1.00 | 54.05 | B | C |
| ATOM | 182 | OE1 | GLU | B | 134 | 2.605 | 46.131 | 84.825 | 1.00 | 55.53 | B | O |
| ATOM | 183 | OE2 | GLU | B | 134 | 4.071 | 46.948 | 86.250 | 1.00 | 54.68 | B | O |
| ATOM | 184 | C | GLU | B | 134 | 3.479 | 48.919 | 81.626 | 1.00 | 43.72 | B | C |
| ATOM | 185 | O | GLU | B | 134 | 4.703 | 48.994 | 81.750 | 1.00 | 42.70 | B | O |
| ATOM | 186 | N | ILE | B | 135 | 2.894 | 48.266 | 80.626 | 1.00 | 41.51 | B | N |
| ATOM | 187 | CA | ILE | B | 135 | 3.691 | 47.603 | 79.608 | 1.00 | 38.50 | B | C |
| ATOM | 188 | CB | ILE | B | 135 | 2.823 | 46.656 | 78.732 | 1.00 | 40.12 | B | C |
| ATOM | 189 | CG2 | ILE | B | 135 | 1.725 | 46.029 | 79.578 | 1.00 | 39.45 | B | C |
| ATOM | 190 | CG1 | ILE | B | 135 | 2.215 | 47.419 | 77.554 | 1.00 | 42.13 | B | C |
| ATOM | 191 | CD1 | ILE | B | 135 | 2.986 | 47.257 | 76.248 | 1.00 | 43.88 | B | C |
| ATOM | 192 | C | ILE | B | 135 | 4.360 | 48.653 | 78.732 | 1.00 | 36.01 | B | C |
| ATOM | 193 | O | ILE | B | 135 | 5.419 | 48.411 | 78.157 | 1.00 | 36.79 | B | O |
| ATOM | 194 | N | VAL | B | 136 | 3.738 | 49.822 | 78.635 | 1.00 | 33.14 | B | N |
| ATOM | 195 | CA | VAL | B | 136 | 4.297 | 50.900 | 77.832 | 1.00 | 30.84 | B | C |
| ATOM | 196 | CB | VAL | B | 136 | 3.277 | 52.046 | 77.631 | 1.00 | 29.03 | B | C |
| ATOM | 197 | CG1 | VAL | B | 136 | 3.960 | 53.248 | 77.000 | 1.00 | 28.49 | B | C |
| ATOM | 198 | CG2 | VAL | B | 136 | 2.135 | 51.577 | 76.750 | 1.00 | 27.80 | B | C |
| ATOM | 199 | C | VAL | B | 136 | 5.528 | 51.443 | 78.546 | 1.00 | 30.54 | B | C |
| ATOM | 200 | O | VAL | B | 136 | 6.571 | 51.658 | 77.927 | 1.00 | 31.20 | B | O |
| ATOM | 201 | N | CYS | B | 137 | 5.404 | 51.655 | 79.854 | 1.00 | 29.11 | B | N |
| ATOM | 202 | CA | CYS | B | 137 | 6.505 | 52.173 | 80.661 | 1.00 | 26.93 | B | C |
| ATOM | 203 | CB | CYS | B | 137 | 6.024 | 52.462 | 82.081 | 1.00 | 26.91 | B | C |
| ATOM | 204 | SG | CYS | B | 137 | 5.120 | 54.011 | 82.267 | 1.00 | 28.49 | B | S |
| ATOM | 205 | C | CYS | B | 137 | 7.649 | 51.173 | 80.707 | 1.00 | 26.18 | B | C |
| ATOM | 206 | O | CYS | B | 137 | 8.816 | 51.553 | 80.743 | 1.00 | 26.25 | B | O |
| ATOM | 207 | N | LYS | B | 138 | 7.302 | 49.892 | 80.705 | 1.00 | 25.66 | B | N |
| ATOM | 208 | CA | LYS | B | 138 | 8.291 | 48.828 | 80.742 | 1.00 | 25.34 | B | C |
| ATOM | 209 | CB | LYS | B | 138 | 7.603 | 47.483 | 80.967 | 1.00 | 27.33 | B | C |
| ATOM | 210 | CG | LYS | B | 138 | 7.126 | 47.270 | 82.389 | 1.00 | 33.42 | B | C |
| ATOM | 211 | CD | LYS | B | 138 | 6.682 | 45.835 | 82.599 | 1.00 | 37.42 | B | C |
| ATOM | 212 | CE | LYS | B | 138 | 6.261 | 45.589 | 84.040 | 1.00 | 40.66 | B | C |
| ATOM | 213 | NZ | LYS | B | 138 | 6.843 | 44.321 | 84.562 | 1.00 | 42.40 | B | N |
| ATOM | 214 | C | LYS | B | 138 | 9.099 | 48.776 | 79.455 | 1.00 | 23.06 | B | C |
| ATOM | 215 | O | LYS | B | 138 | 10.302 | 48.526 | 79.485 | 1.00 | 22.88 | B | O |
| ATOM | 216 | N | GLY | B | 139 | 8.430 | 49.012 | 78.329 | 1.00 | 21.77 | B | N |
| ATOM | 217 | CA | GLY | B | 139 | 9.103 | 48.986 | 77.045 | 1.00 | 18.66 | B | C |
| ATOM | 218 | C | GLY | B | 139 | 10.071 | 50.143 | 76.912 | 1.00 | 18.79 | B | C |
| ATOM | 219 | O | GLY | B | 139 | 11.208 | 49.963 | 76.471 | 1.00 | 18.11 | B | O |
| ATOM | 220 | N | LEU | B | 140 | 9.622 | 51.335 | 77.301 | 1.00 | 18.89 | B | N |
| ATOM | 221 | CA | LEU | B | 140 | 10.452 | 52.531 | 77.221 | 1.00 | 19.07 | B | C |
| ATOM | 222 | CB | LEU | B | 140 | 9.633 | 53.769 | 77.605 | 1.00 | 19.60 | B | C |
| ATOM | 223 | CG | LEU | B | 140 | 8.578 | 54.202 | 76.568 | 1.00 | 21.05 | B | C |
| ATOM | 224 | CD1 | LEU | B | 140 | 7.797 | 55.395 | 77.091 | 1.00 | 18.84 | B | C |
| ATOM | 225 | CD2 | LEU | B | 140 | 9.257 | 54.554 | 75.251 | 1.00 | 19.35 | B | C |
| ATOM | 226 | C | LEU | B | 140 | 11.666 | 52.386 | 78.132 | 1.00 | 18.95 | B | C |
| ATOM | 227 | O | LEU | B | 140 | 12.771 | 52.809 | 77.793 | 1.00 | 17.60 | B | O |
| ATOM | 228 | N | TYR | B | 141 | 11.459 | 51.773 | 79.292 | 1.00 | 19.62 | B | N |
| ATOM | 229 | CA | TYR | B | 141 | 12.550 | 51.561 | 80.237 | 1.00 | 18.34 | B | C |
| ATOM | 230 | CB | TYR | B | 141 | 12.018 | 50.925 | 81.526 | 1.00 | 18.49 | B | C |
| ATOM | 231 | CG | TYR | B | 141 | 13.097 | 50.296 | 82.374 | 1.00 | 20.16 | B | C |
| ATOM | 232 | CD1 | TYR | B | 141 | 13.278 | 48.916 | 82.390 | 1.00 | 20.40 | B | C |
| ATOM | 233 | CE1 | TYR | B | 141 | 14.303 | 48.333 | 83.129 | 1.00 | 22.93 | B | C |
| ATOM | 234 | CD2 | TYR | B | 141 | 13.970 | 51.084 | 83.127 | 1.00 | 20.98 | B | C |
| ATOM | 235 | CE2 | TYR | B | 141 | 15.002 | 50.511 | 83.870 | 1.00 | 21.75 | B | C |
| ATOM | 236 | CZ | TYR | B | 141 | 15.163 | 49.134 | 83.862 | 1.00 | 23.38 | B | C |
| ATOM | 237 | OH | TYR | B | 141 | 16.199 | 48.550 | 84.558 | 1.00 | 24.45 | B | O |
| ATOM | 238 | C | TYR | B | 141 | 13.611 | 50.651 | 79.609 | 1.00 | 17.90 | B | C |
| ATOM | 239 | O | TYR | B | 141 | 14.806 | 50.970 | 79.619 | 1.00 | 16.17 | B | O |
| ATOM | 240 | N | ARG | B | 142 | 13.177 | 49.521 | 79.057 | 1.00 | 17.24 | B | N |
| ATOM | 241 | CA | ARG | B | 142 | 14.112 | 48.582 | 78.445 | 1.00 | 18.38 | B | C |
| ATOM | 242 | CB | ARG | B | 142 | 13.388 | 47.292 | 78.052 | 1.00 | 18.24 | B | C |
| ATOM | 243 | CG | ARG | B | 142 | 14.165 | 46.464 | 77.054 | 1.00 | 22.98 | B | C |
| ATOM | 244 | CD | ARG | B | 142 | 13.842 | 44.981 | 77.106 | 1.00 | 23.45 | B | C |
| ATOM | 245 | NE | ARG | B | 142 | 14.812 | 44.235 | 76.304 | 1.00 | 25.00 | B | N |
| ATOM | 246 | CZ | ARG | B | 142 | 14.546 | 43.116 | 75.638 | 1.00 | 26.20 | B | C |
| ATOM | 247 | NH1 | ARG | B | 142 | 13.322 | 42.594 | 75.671 | 1.00 | 25.36 | B | N |
| ATOM | 248 | NH2 | ARG | B | 142 | 15.506 | 42.526 | 74.927 | 1.00 | 22.16 | B | N |
| ATOM | 249 | C | ARG | B | 142 | 14.820 | 49.180 | 77.229 | 1.00 | 18.77 | B | C |
| ATOM | 250 | O | ARG | B | 142 | 15.986 | 48.884 | 76.977 | 1.00 | 19.74 | B | O |
| ATOM | 251 | N | ALA | B | 143 | 14.123 | 50.030 | 76.479 | 1.00 | 18.77 | B | N |
| ATOM | 252 | CA | ALA | B | 143 | 14.719 | 50.654 | 75.301 | 1.00 | 17.05 | B | C |
| ATOM | 253 | CB | ALA | B | 143 | 13.663 | 51.435 | 74.528 | 1.00 | 17.76 | B | C |
| ATOM | 254 | C | ALA | B | 143 | 15.868 | 51.573 | 75.703 | 1.00 | 16.23 | B | C |
| ATOM | 255 | O | ALA | B | 143 | 16.911 | 51.603 | 75.049 | 1.00 | 14.53 | B | O |
| ATOM | 256 | N | LEU | B | 144 | 15.674 | 52.322 | 76.785 | 1.00 | 16.01 | B | N |
| ATOM | 257 | CA | LEU | B | 144 | 16.710 | 53.229 | 77.277 | 1.00 | 15.45 | B | C |
| ATOM | 258 | CB | LEU | B | 144 | 16.128 | 54.162 | 78.342 | 1.00 | 15.13 | B | C |
| ATOM | 259 | CG | LEU | B | 144 | 15.234 | 55.289 | 77.817 | 1.00 | 16.00 | B | C |
| ATOM | 260 | CD1 | LEU | B | 144 | 14.546 | 56.006 | 78.971 | 1.00 | 14.14 | B | C |
| ATOM | 261 | CD2 | LEU | B | 144 | 16.085 | 56.263 | 77.014 | 1.00 | 15.82 | B | C |
| ATOM | 262 | C | LEU | B | 144 | 17.863 | 52.412 | 77.863 | 1.00 | 15.10 | B | C |
| ATOM | 263 | O | LEU | B | 144 | 19.026 | 52.819 | 77.806 | 1.00 | 13.81 | B | O |
| ATOM | 264 | N | CYS | B | 145 | 17.528 | 51.251 | 78.416 | 1.00 | 16.31 | B | N |
| ATOM | 265 | CA | CYS | B | 145 | 18.526 | 50.362 | 78.999 | 1.00 | 20.19 | B | C |
| ATOM | 266 | CB | CYS | B | 145 | 17.847 | 49.225 | 79.769 | 1.00 | 24.39 | B | C |
| ATOM | 267 | SG | CYS | B | 145 | 17.848 | 49.448 | 81.556 | 1.00 | 35.84 | B | S |
| ATOM | 268 | C | CYS | B | 145 | 19.396 | 49.776 | 77.906 | 1.00 | 18.15 | B | C |
| ATOM | 269 | O | CYS | B | 145 | 20.605 | 49.630 | 78.075 | 1.00 | 19.64 | B | O |
| ATOM | 270 | N | ILE | B | 146 | 18.767 | 49.426 | 76.789 | 1.00 | 17.89 | B | N |
| ATOM | 271 | CA | ILE | B | 146 | 19.477 | 48.868 | 75.648 | 1.00 | 15.40 | B | C |
| ATOM | 272 | CB | ILE | B | 146 | 18.498 | 48.484 | 74.523 | 1.00 | 15.67 | B | C |
| ATOM | 273 | CG2 | ILE | B | 146 | 19.241 | 48.319 | 73.205 | 1.00 | 16.61 | B | C |
| ATOM | 274 | CG1 | ILE | B | 146 | 17.777 | 47.190 | 74.895 | 1.00 | 13.90 | B | C |
| ATOM | 275 | CD1 | ILE | B | 146 | 16.497 | 46.962 | 74.124 | 1.00 | 14.78 | B | C |
| ATOM | 276 | C | ILE | B | 146 | 20.488 | 49.882 | 75.117 | 1.00 | 15.58 | B | C |
| ATOM | 277 | O | ILE | B | 146 | 21.659 | 49.547 | 74.927 | 1.00 | 15.05 | B | O |
| ATOM | 278 | N | ARG | B | 147 | 20.051 | 51.123 | 74.897 | 1.00 | 14.65 | B | N |
| ATOM | 279 | CA | ARG | B | 147 | 20.959 | 52.144 | 74.381 | 1.00 | 13.48 | B | C |
| ATOM | 280 | CB | ARG | B | 147 | 20.214 | 53.447 | 74.062 | 1.00 | 8.91 | B | C |
| ATOM | 281 | CG | ARG | B | 147 | 21.173 | 54.588 | 73.707 | 1.00 | 5.87 | B | C |
| ATOM | 282 | CD | ARG | B | 147 | 20.502 | 55.733 | 72.960 | 1.00 | 8.19 | B | C |
| ATOM | 283 | NE | ARG | B | 147 | 21.463 | 56.777 | 72.596 | 1.00 | 10.82 | B | N |
| ATOM | 284 | CZ | ARG | B | 147 | 22.234 | 56.754 | 71.506 | 1.00 | 12.80 | B | C |
| ATOM | 285 | NH1 | ARG | B | 147 | 22.163 | 55.728 | 70.659 | 1.00 | 9.66 | B | N |
| ATOM | 286 | NH2 | ARG | B | 147 | 23.075 | 57.759 | 71.258 | 1.00 | 7.70 | B | N |
| ATOM | 287 | C | ARG | B | 147 | 22.113 | 52.450 | 75.335 | 1.00 | 14.77 | B | C |
| ATOM | 288 | O | ARG | B | 147 | 23.265 | 52.576 | 74.907 | 1.00 | 16.74 | B | O |
| ATOM | 289 | N | GLU | B | 148 | 21.805 | 52.581 | 76.623 | 1.00 | 15.15 | B | N |
| ATOM | 290 | CA | GLU | B | 148 | 22.827 | 52.871 | 77.619 | 1.00 | 15.71 | B | C |
| ATOM | 291 | CB | GLU | B | 148 | 22.215 | 52.951 | 79.022 | 1.00 | 17.06 | B | C |
| ATOM | 292 | CG | GLU | B | 148 | 23.267 | 53.163 | 80.126 | 1.00 | 17.79 | B | C |
| ATOM | 293 | CD | GLU | B | 148 | 22.716 | 52.962 | 81.526 | 1.00 | 18.45 | B | C |
| ATOM | 294 | OE1 | GLU | B | 148 | 22.842 | 53.893 | 82.346 | 1.00 | 18.52 | B | O |
| ATOM | 295 | OE2 | GLU | B | 148 | 22.160 | 51.879 | 81.804 | 1.00 | 19.12 | B | O |
| ATOM | 296 | C | GLU | B | 148 | 23.899 | 51.791 | 77.616 | 1.00 | 15.49 | B | C |
| ATOM | 297 | O | GLU | B | 148 | 25.089 | 52.085 | 77.703 | 1.00 | 15.86 | B | O |
| ATOM | 298 | N | LYS | B | 149 | 23.464 | 50.538 | 77.529 | 1.00 | 15.99 | B | N |
| ATOM | 299 | CA | LYS | B | 149 | 24.375 | 49.401 | 77.525 | 1.00 | 17.44 | B | C |
| ATOM | 300 | CB | LYS | B | 149 | 23.566 | 48.100 | 77.531 | 1.00 | 16.93 | B | C |
| ATOM | 301 | CG | LYS | B | 149 | 24.422 | 46.836 | 77.483 | 1.00 | 19.18 | B | C |
| ATOM | 302 | CD | LYS | B | 149 | 23.569 | 45.578 | 77.495 | 1.00 | 17.99 | B | C |
| ATOM | 303 | CE | LYS | B | 149 | 22.720 | 45.479 | 76.226 | 1.00 | 22.48 | B | C |
| ATOM | 304 | NZ | LYS | B | 149 | 21.866 | 44.252 | 76.164 | 1.00 | 21.41 | B | N |
| ATOM | 305 | C | LYS | B | 149 | 25.328 | 49.418 | 76.325 | 1.00 | 18.31 | B | C |
| ATOM | 306 | O | LYS | B | 149 | 26.543 | 49.262 | 76.478 | 1.00 | 18.19 | B | O |
| ATOM | 307 | N | TYR | B | 150 | 24.772 | 49.616 | 75.132 | 1.00 | 17.82 | B | N |
| ATOM | 308 | CA | TYR | B | 150 | 25.565 | 49.641 | 73.913 | 1.00 | 16.69 | B | C |
| ATOM | 309 | CB | TYR | B | 150 | 24.639 | 49.566 | 72.696 | 1.00 | 19.80 | B | C |
| ATOM | 310 | CG | TYR | B | 150 | 24.021 | 48.197 | 72.513 | 1.00 | 20.86 | B | C |
| ATOM | 311 | CD1 | TYR | B | 150 | 24.598 | 47.259 | 71.666 | 1.00 | 24.27 | B | C |
| ATOM | 312 | CE1 | TYR | B | 150 | 24.067 | 45.969 | 71.546 | 1.00 | 25.37 | B | C |
| ATOM | 313 | CD2 | TYR | B | 150 | 22.893 | 47.817 | 73.232 | 1.00 | 23.54 | B | C |
| ATOM | 314 | CE2 | TYR | B | 150 | 22.355 | 46.534 | 73.119 | 1.00 | 23.51 | B | C |
| ATOM | 315 | CZ | TYR | B | 150 | 22.950 | 45.618 | 72.279 | 1.00 | 22.67 | B | C |
| ATOM | 316 | OH | TYR | B | 150 | 22.446 | 44.344 | 72.191 | 1.00 | 21.08 | B | O |
| ATOM | 317 | C | TYR | B | 150 | 26.473 | 50.862 | 73.825 | 1.00 | 16.80 | B | C |
| ATOM | 318 | O | TYR | B | 150 | 27.547 | 50.801 | 73.224 | 1.00 | 14.63 | B | O |
| ATOM | 319 | N | MET | B | 151 | 26.057 | 51.970 | 74.433 | 1.00 | 16.87 | B | N |
| ATOM | 320 | CA | MET | B | 151 | 26.874 | 53.179 | 74.410 | 1.00 | 17.39 | B | C |
| ATOM | 321 | CB | MET | B | 151 | 26.057 | 54.391 | 74.874 | 1.00 | 16.52 | B | C |
| ATOM | 322 | CG | MET | B | 151 | 25.077 | 54.944 | 73.836 | 1.00 | 17.79 | B | C |
| ATOM | 323 | SD | MET | B | 151 | 25.780 | 55.236 | 72.170 | 1.00 | 16.08 | B | S |
| ATOM | 324 | CE | MET | B | 151 | 25.228 | 53.764 | 71.319 | 1.00 | 13.16 | B | C |
| ATOM | 325 | C | MET | B | 151 | 28.105 | 53.020 | 75.302 | 1.00 | 19.53 | B | C |
| ATOM | 326 | O | MET | B | 151 | 29.229 | 53.285 | 74.877 | 1.00 | 21.79 | B | O |
| ATOM | 327 | N | LEU | B | 152 | 27.895 | 52.581 | 76.539 | 1.00 | 20.21 | B | N |
| ATOM | 328 | CA | LEU | B | 152 | 28.999 | 52.407 | 77.482 | 1.00 | 21.62 | B | C |
| ATOM | 329 | CB | LEU | B | 152 | 28.456 | 52.052 | 78.868 | 1.00 | 23.45 | B | C |
| ATOM | 330 | CG | LEU | B | 152 | 27.496 | 53.056 | 79.517 | 1.00 | 24.76 | B | C |
| ATOM | 331 | CD1 | LEU | B | 152 | 27.213 | 52.639 | 80.957 | 1.00 | 25.95 | B | C |
| ATOM | 332 | CD2 | LEU | B | 152 | 28.100 | 54.453 | 79.470 | 1.00 | 24.56 | B | C |
| ATOM | 333 | C | LEU | B | 152 | 29.973 | 51.329 | 77.027 | 1.00 | 20.64 | B | C |
| ATOM | 334 | O | LEU | B | 152 | 31.187 | 51.478 | 77.157 | 1.00 | 20.04 | B | O |
| ATOM | 335 | N | LYS | B | 153 | 29.429 | 50.249 | 76.483 | 1.00 | 20.07 | B | N |
| ATOM | 336 | CA | LYS | B | 153 | 30.235 | 49.134 | 76.013 | 1.00 | 20.78 | B | C |
| ATOM | 337 | CB | LYS | B | 153 | 29.315 | 47.981 | 75.617 | 1.00 | 23.04 | B | C |
| ATOM | 338 | CG | LYS | B | 153 | 30.047 | 46.709 | 75.266 | 1.00 | 28.86 | B | C |
| ATOM | 339 | CD | LYS | B | 153 | 29.114 | 45.693 | 74.629 | 1.00 | 32.79 | B | C |
| ATOM | 340 | CE | LYS | B | 153 | 27.876 | 45.444 | 75.479 | 1.00 | 33.83 | B | C |
| ATOM | 341 | NZ | LYS | B | 153 | 26.761 | 44.883 | 74.659 | 1.00 | 39.07 | B | N |
| ATOM | 342 | C | LYS | B | 153 | 31.149 | 49.492 | 74.842 | 1.00 | 20.94 | B | C |
| ATOM | 343 | O | LYS | B | 153 | 32.126 | 48.789 | 74.581 | 1.00 | 21.72 | B | O |
| ATOM | 344 | N | SER | B | 154 | 30.839 | 50.577 | 74.137 | 1.00 | 20.20 | B | N |
| ATOM | 345 | CA | SER | B | 154 | 31.643 | 50.993 | 72.990 | 1.00 | 19.86 | B | C |
| ATOM | 346 | CB | SER | B | 154 | 30.777 | 51.096 | 71.727 | 1.00 | 19.37 | B | C |
| ATOM | 347 | OG | SER | B | 154 | 29.712 | 52.017 | 71.899 | 1.00 | 20.98 | B | O |
| ATOM | 348 | C | SER | B | 154 | 32.318 | 52.326 | 73.247 | 1.00 | 19.93 | B | C |
| ATOM | 349 | O | SER | B | 154 | 32.841 | 52.952 | 72.329 | 1.00 | 20.80 | B | O |
| ATOM | 350 | N | PHE | B | 155 | 32.299 | 52.755 | 74.502 | 1.00 | 18.94 | B | N |
| ATOM | 351 | CA | PHE | B | 155 | 32.918 | 54.008 | 74.896 | 1.00 | 17.68 | B | C |
| ATOM | 352 | CB | PHE | B | 155 | 34.423 | 53.933 | 74.666 | 1.00 | 21.11 | B | C |
| ATOM | 353 | CG | PHE | B | 155 | 35.097 | 52.895 | 75.512 | 1.00 | 22.85 | B | C |
| ATOM | 354 | CD1 | PHE | B | 155 | 35.565 | 53.215 | 76.783 | 1.00 | 23.41 | B | C |
| ATOM | 355 | CD2 | PHE | B | 155 | 35.204 | 51.581 | 75.066 | 1.00 | 23.57 | B | C |
| ATOM | 356 | CE1 | PHE | B | 155 | 36.128 | 52.238 | 77.609 | 1.00 | 24.33 | B | C |
| ATOM | 357 | CE2 | PHE | B | 155 | 35.765 | 50.594 | 75.882 | 1.00 | 25.04 | B | C |
| ATOM | 358 | CZ | PHE | B | 155 | 36.227 | 50.927 | 77.160 | 1.00 | 24.26 | B | C |
| ATOM | 359 | C | PHE | B | 155 | 32.333 | 55.223 | 74.201 | 1.00 | 18.22 | B | C |
| ATOM | 360 | O | PHE | B | 155 | 33.047 | 56.170 | 73.861 | 1.00 | 17.18 | B | O |
| ATOM | 361 | N | GLN | B | 156 | 31.023 | 55.190 | 73.993 | 1.00 | 16.37 | B | N |
| ATOM | 362 | CA | GLN | B | 156 | 30.335 | 56.307 | 73.374 | 1.00 | 16.82 | B | C |
| ATOM | 363 | CB | GLN | B | 156 | 29.456 | 55.816 | 72.222 | 1.00 | 16.29 | B | C |
| ATOM | 364 | CG | GLN | B | 156 | 30.299 | 55.358 | 71.022 | 1.00 | 14.15 | B | C |
| ATOM | 365 | CD | GLN | B | 156 | 29.478 | 55.091 | 69.785 | 1.00 | 12.40 | B | C |
| ATOM | 366 | OE1 | GLN | B | 156 | 28.850 | 54.037 | 69.654 | 1.00 | 12.04 | B | O |
| ATOM | 367 | NE2 | GLN | B | 156 | 29.478 | 56.043 | 68.863 | 1.00 | 9.98 | B | N |
| ATOM | 368 | C | GLN | B | 156 | 29.526 | 56.977 | 74.477 | 1.00 | 17.47 | B | C |
| ATOM | 369 | O | GLN | B | 156 | 29.420 | 56.435 | 75.577 | 1.00 | 18.51 | B | O |
| ATOM | 370 | N | ARG | B | 157 | 28.959 | 58.144 | 74.194 | 1.00 | 16.71 | B | N |
| ATOM | 371 | CA | ARG | B | 157 | 28.228 | 58.894 | 75.210 | 1.00 | 16.26 | B | C |
| ATOM | 372 | CB | ARG | B | 157 | 28.407 | 60.392 | 74.935 | 1.00 | 14.80 | B | C |
| ATOM | 373 | CG | ARG | B | 157 | 29.872 | 60.792 | 74.712 | 1.00 | 16.45 | B | C |
| ATOM | 374 | CD | ARG | B | 157 | 30.032 | 62.229 | 74.220 | 1.00 | 17.62 | B | C |
| ATOM | 375 | NE | ARG | B | 157 | 29.535 | 62.408 | 72.854 | 1.00 | 18.86 | B | N |
| ATOM | 376 | CZ | ARG | B | 157 | 29.579 | 63.555 | 72.177 | 1.00 | 17.11 | B | C |
| ATOM | 377 | NH1 | ARG | B | 157 | 29.099 | 63.616 | 70.940 | 1.00 | 14.93 | B | N |
| ATOM | 378 | NH2 | ARG | B | 157 | 30.107 | 64.639 | 72.726 | 1.00 | 14.55 | B | N |
| ATOM | 379 | C | ARG | B | 157 | 26.748 | 58.591 | 75.462 | 1.00 | 17.40 | B | C |
| ATOM | 380 | O | ARG | B | 157 | 26.008 | 58.200 | 74.558 | 1.00 | 17.95 | B | O |
| ATOM | 381 | N | PHE | B | 158 | 26.347 | 58.754 | 76.724 | 1.00 | 17.59 | B | N |
| ATOM | 382 | CA | PHE | B | 158 | 24.962 | 58.580 | 77.185 | 1.00 | 17.21 | B | C |
| ATOM | 383 | CB | PHE | B | 158 | 24.683 | 57.151 | 77.626 | 1.00 | 15.80 | B | C |
| ATOM | 384 | CG | PHE | B | 158 | 23.218 | 56.862 | 77.847 | 1.00 | 16.41 | B | C |
| ATOM | 385 | CD1 | PHE | B | 158 | 22.684 | 56.831 | 79.133 | 1.00 | 14.70 | B | C |
| ATOM | 386 | CD2 | PHE | B | 158 | 22.372 | 56.622 | 76.769 | 1.00 | 14.38 | B | C |
| ATOM | 387 | CE1 | PHE | B | 158 | 21.331 | 56.566 | 79.346 | 1.00 | 13.05 | B | C |
| ATOM | 388 | CE2 | PHE | B | 158 | 21.014 | 56.354 | 76.972 | 1.00 | 16.49 | B | C |
| ATOM | 389 | CZ | PHE | B | 158 | 20.494 | 56.327 | 78.267 | 1.00 | 15.92 | B | C |
| ATOM | 390 | C | PHE | B | 158 | 24.786 | 59.532 | 78.373 | 1.00 | 17.97 | B | C |
| ATOM | 391 | O | PHE | B | 158 | 25.557 | 59.483 | 79.327 | 1.00 | 18.43 | B | O |
| ATOM | 392 | N | PRO | B | 159 | 23.764 | 60.405 | 78.330 | 1.00 | 17.84 | B | N |
| ATOM | 393 | CD | PRO | B | 159 | 22.757 | 60.487 | 77.261 | 1.00 | 16.45 | B | C |
| ATOM | 394 | CA | PRO | B | 159 | 23.497 | 61.378 | 79.396 | 1.00 | 18.34 | B | C |
| ATOM | 395 | CB | PRO | B | 159 | 22.232 | 62.093 | 78.926 | 1.00 | 17.77 | B | C |
| ATOM | 396 | CG | PRO | B | 159 | 21.611 | 61.149 | 77.943 | 1.00 | 17.82 | B | C |
| ATOM | 397 | C | PRO | B | 159 | 23.339 | 60.796 | 80.794 | 1.00 | 18.75 | B | C |
| ATOM | 398 | O | PRO | B | 159 | 22.885 | 59.666 | 80.962 | 1.00 | 20.43 | B | O |
| ATOM | 399 | N | LYS | B | 160 | 23.707 | 61.593 | 81.793 | 1.00 | 19.29 | B | N |
| ATOM | 400 | CA | LYS | B | 160 | 23.624 | 61.181 | 83.191 | 1.00 | 20.33 | B | C |
| ATOM | 401 | CB | LYS | B | 160 | 24.450 | 62.128 | 84.069 | 1.00 | 20.98 | B | C |
| ATOM | 402 | CG | LYS | B | 160 | 25.931 | 61.797 | 84.105 | 1.00 | 24.43 | B | C |
| ATOM | 403 | CD | LYS | B | 160 | 26.775 | 62.946 | 84.663 | 1.00 | 26.73 | B | C |
| ATOM | 404 | CE | LYS | B | 160 | 26.326 | 64.308 | 84.137 | 1.00 | 31.09 | B | C |
| ATOM | 405 | NZ | LYS | B | 160 | 26.960 | 64.664 | 82.831 | 1.00 | 33.29 | B | N |
| ATOM | 406 | C | LYS | B | 160 | 22.207 | 61.105 | 83.748 | 1.00 | 18.68 | B | C |
| ATOM | 407 | O | LYS | B | 160 | 21.833 | 60.096 | 84.345 | 1.00 | 17.83 | B | O |
| ATOM | 408 | N | THR | B | 161 | 21.405 | 62.148 | 83.545 | 1.00 | 19.18 | B | N |
| ATOM | 409 | CA | THR | B | 161 | 20.067 | 62.121 | 84.120 | 1.00 | 20.29 | B | C |
| ATOM | 410 | CB | THR | B | 161 | 19.286 | 63.436 | 83.871 | 1.00 | 20.52 | B | C |
| ATOM | 411 | OG1 | THR | B | 161 | 18.299 | 63.235 | 82.861 | 1.00 | 28.20 | B | O |
| ATOM | 412 | CG2 | THR | B | 161 | 20.223 | 64.550 | 83.489 | 1.00 | 18.47 | B | C |
| ATOM | 413 | C | THR | B | 161 | 19.226 | 60.905 | 83.754 | 1.00 | 19.85 | B | C |
| ATOM | 414 | O | THR | B | 161 | 18.554 | 60.352 | 84.619 | 1.00 | 21.50 | B | O |
| ATOM | 415 | N | PRO | B | 162 | 19.236 | 60.465 | 82.482 | 1.00 | 19.73 | B | N |
| ATOM | 416 | CD | PRO | B | 162 | 19.891 | 60.980 | 81.269 | 1.00 | 19.15 | B | C |
| ATOM | 417 | CA | PRO | B | 162 | 18.417 | 59.278 | 82.194 | 1.00 | 18.82 | B | C |
| ATOM | 418 | CB | PRO | B | 162 | 18.552 | 59.094 | 80.680 | 1.00 | 17.22 | B | C |
| ATOM | 419 | CG | PRO | B | 162 | 19.059 | 60.389 | 80.172 | 1.00 | 19.04 | B | C |
| ATOM | 420 | C | PRO | B | 162 | 18.954 | 58.062 | 82.964 | 1.00 | 18.32 | B | C |
| ATOM | 421 | O | PRO | B | 162 | 18.202 | 57.181 | 83.361 | 1.00 | 18.39 | B | O |
| ATOM | 422 | N | SER | B | 163 | 20.266 | 58.024 | 83.165 | 1.00 | 20.41 | B | N |
| ATOM | 423 | CA | SER | B | 163 | 20.895 | 56.923 | 83.884 | 1.00 | 22.04 | B | C |
| ATOM | 424 | CB | SER | B | 163 | 22.415 | 57.055 | 83.814 | 1.00 | 23.35 | B | C |
| ATOM | 425 | OG | SER | B | 163 | 22.888 | 56.726 | 82.514 | 1.00 | 24.35 | B | O |
| ATOM | 426 | C | SER | B | 163 | 20.435 | 56.936 | 85.336 | 1.00 | 21.09 | B | C |
| ATOM | 427 | O | SER | B | 163 | 20.087 | 55.897 | 85.902 | 1.00 | 21.53 | B | O |
| ATOM | 428 | N | LYS | B | 164 | 20.431 | 58.123 | 85.929 | 1.00 | 20.50 | B | N |
| ATOM | 429 | CA | LYS | B | 164 | 19.993 | 58.277 | 87.307 | 1.00 | 18.75 | B | C |
| ATOM | 430 | CB | LYS | B | 164 | 19.973 | 59.753 | 87.689 | 1.00 | 17.87 | B | C |
| ATOM | 431 | CG | LYS | B | 164 | 21.348 | 60.309 | 87.973 | 1.00 | 18.05 | B | C |
| ATOM | 432 | CD | LYS | B | 164 | 21.285 | 61.769 | 88.345 | 1.00 | 19.51 | B | C |
| ATOM | 433 | CE | LYS | B | 164 | 22.676 | 62.340 | 88.468 | 1.00 | 21.18 | B | C |
| ATOM | 434 | NZ | LYS | B | 164 | 22.677 | 63.808 | 88.236 | 1.00 | 26.53 | B | N |
| ATOM | 435 | C | LYS | B | 164 | 18.605 | 57.674 | 87.487 | 1.00 | 19.81 | B | C |
| ATOM | 436 | O | LYS | B | 164 | 18.359 | 56.958 | 88.456 | 1.00 | 19.08 | B | O |
| ATOM | 437 | N | TYR | B | 165 | 17.702 | 57.943 | 86.550 | 1.00 | 17.98 | B | N |
| ATOM | 438 | CA | TYR | B | 165 | 16.350 | 57.404 | 86.648 | 1.00 | 18.67 | B | C |
| ATOM | 439 | CB | TYR | B | 165 | 15.430 | 58.074 | 85.627 | 1.00 | 17.40 | B | C |
| ATOM | 440 | CG | TYR | B | 165 | 14.836 | 59.366 | 86.122 | 1.00 | 17.32 | B | C |
| ATOM | 441 | CD1 | TYR | B | 165 | 13.653 | 59.375 | 86.858 | 1.00 | 17.76 | B | C |
| ATOM | 442 | CE1 | TYR | B | 165 | 13.111 | 60.566 | 87.333 | 1.00 | 18.31 | B | C |
| ATOM | 443 | CD2 | TYR | B | 165 | 15.463 | 60.581 | 85.870 | 1.00 | 17.37 | B | C |
| ATOM | 444 | CE2 | TYR | B | 165 | 14.930 | 61.777 | 86.340 | 1.00 | 19.42 | B | C |
| ATOM | 445 | CZ | TYR | B | 165 | 13.758 | 61.761 | 87.069 | 1.00 | 19.40 | B | C |
| ATOM | 446 | OH | TYR | B | 165 | 13.243 | 62.943 | 87.545 | 1.00 | 22.54 | B | O |
| ATOM | 447 | C | TYR | B | 165 | 16.312 | 55.895 | 86.448 | 1.00 | 19.97 | B | C |
| ATOM | 448 | O | TYR | B | 165 | 15.466 | 55.209 | 87.024 | 1.00 | 19.75 | B | O |
| ATOM | 449 | N | LEU | B | 166 | 17.225 | 55.378 | 85.629 | 1.00 | 21.86 | B | N |
| ATOM | 450 | CA | LEU | B | 166 | 17.263 | 53.943 | 85.366 | 1.00 | 22.77 | B | C |
| ATOM | 451 | CB | LEU | B | 166 | 18.202 | 53.635 | 84.191 | 1.00 | 23.94 | B | C |
| ATOM | 452 | CG | LEU | B | 166 | 17.775 | 54.073 | 82.776 | 1.00 | 23.15 | B | C |
| ATOM | 453 | CD1 | LEU | B | 166 | 18.893 | 53.753 | 81.791 | 1.00 | 20.70 | B | C |
| ATOM | 454 | CD2 | LEU | B | 166 | 16.488 | 53.370 | 82.360 | 1.00 | 19.92 | B | C |
| ATOM | 455 | C | LEU | B | 166 | 17.720 | 53.205 | 86.623 | 1.00 | 23.31 | B | C |
| ATOM | 456 | O | LEU | B | 166 | 17.152 | 52.174 | 86.986 | 1.00 | 23.77 | B | O |
| ATOM | 457 | N | ARG | B | 167 | 18.741 | 53.739 | 87.286 | 1.00 | 22.80 | B | N |
| ATOM | 458 | CA | ARG | B | 167 | 19.247 | 53.126 | 88.509 | 1.00 | 23.49 | B | C |
| ATOM | 459 | CB | ARG | B | 167 | 20.459 | 53.900 | 89.029 | 1.00 | 21.90 | B | C |
| ATOM | 460 | CG | ARG | B | 167 | 21.703 | 53.815 | 88.149 | 1.00 | 20.65 | B | C |
| ATOM | 461 | CD | ARG | B | 167 | 22.136 | 52.377 | 87.884 | 1.00 | 23.03 | B | C |
| ATOM | 462 | NE | ARG | B | 167 | 21.423 | 51.795 | 86.746 | 1.00 | 26.39 | B | N |
| ATOM | 463 | CZ | ARG | B | 167 | 21.648 | 52.112 | 85.470 | 1.00 | 26.04 | B | C |
| ATOM | 464 | NH1 | ARG | B | 167 | 22.574 | 53.010 | 85.152 | 1.00 | 24.54 | B | N |
| ATOM | 465 | NH2 | ARG | B | 167 | 20.930 | 51.547 | 84.506 | 1.00 | 24.81 | B | N |
| ATOM | 466 | C | ARG | B | 167 | 18.138 | 53.112 | 89.569 | 1.00 | 24.85 | B | C |
| ATOM | 467 | O | ARG | B | 167 | 17.939 | 52.107 | 90.252 | 1.00 | 25.27 | B | O |
| ATOM | 468 | N | SER | B | 168 | 17.410 | 54.222 | 89.683 | 1.00 | 25.45 | B | N |
| ATOM | 469 | CA | SER | B | 168 | 16.311 | 54.347 | 90.643 | 1.00 | 27.29 | B | C |
| ATOM | 470 | CB | SER | B | 168 | 15.667 | 55.728 | 90.554 | 1.00 | 26.48 | B | C |
| ATOM | 471 | OG | SER | B | 168 | 16.650 | 56.730 | 90.402 | 1.00 | 32.86 | B | O |
| ATOM | 472 | C | SER | B | 168 | 15.232 | 53.313 | 90.398 | 1.00 | 27.47 | B | C |
| ATOM | 473 | O | SER | B | 168 | 14.756 | 52.659 | 91.327 | 1.00 | 27.11 | B | O |
| ATOM | 474 | N | ILE | B | 169 | 14.832 | 53.182 | 89.139 | 1.00 | 28.38 | B | N |
| ATOM | 475 | CA | ILE | B | 169 | 13.795 | 52.231 | 88.785 | 1.00 | 27.72 | B | C |
| ATOM | 476 | CB | ILE | B | 169 | 13.468 | 52.310 | 87.280 | 1.00 | 25.93 | B | C |
| ATOM | 477 | CG2 | ILE | B | 169 | 12.542 | 51.168 | 86.885 | 1.00 | 23.19 | B | C |
| ATOM | 478 | CG1 | ILE | B | 169 | 12.837 | 53.671 | 86.968 | 1.00 | 26.15 | B | C |
| ATOM | 479 | CD1 | ILE | B | 169 | 12.268 | 53.802 | 85.569 | 1.00 | 27.08 | B | C |
| ATOM | 480 | C | ILE | B | 169 | 14.252 | 50.828 | 89.137 | 1.00 | 28.74 | B | C |
| ATOM | 481 | O | ILE | B | 169 | 13.444 | 49.973 | 89.498 | 1.00 | 29.95 | B | O |
| ATOM | 482 | N | GLU | B | 170 | 15.558 | 50.610 | 89.041 | 1.00 | 31.23 | B | N |
| ATOM | 483 | CA | GLU | B | 170 | 16.157 | 49.313 | 89.324 | 1.00 | 34.23 | B | C |
| ATOM | 484 | CB | GLU | B | 170 | 17.567 | 49.259 | 88.750 | 1.00 | 33.88 | B | C |
| ATOM | 485 | CG | GLU | B | 170 | 17.630 | 48.821 | 87.316 | 1.00 | 36.24 | B | C |
| ATOM | 486 | CD | GLU | B | 170 | 18.890 | 49.300 | 86.634 | 1.00 | 38.16 | B | C |
| ATOM | 487 | OE1 | GLU | B | 170 | 18.856 | 49.518 | 85.400 | 1.00 | 39.69 | B | O |
| ATOM | 488 | OE2 | GLU | B | 170 | 19.913 | 49.458 | 87.336 | 1.00 | 38.19 | B | O |
| ATOM | 489 | C | GLU | B | 170 | 16.220 | 49.007 | 90.813 | 1.00 | 36.02 | B | C |
| ATOM | 490 | O | GLU | B | 170 | 16.153 | 47.847 | 91.222 | 1.00 | 36.52 | B | O |
| ATOM | 491 | N | GLY | B | 171 | 16.357 | 50.051 | 91.620 | 1.00 | 37.33 | B | N |
| ATOM | 492 | CA | GLY | B | 171 | 16.434 | 49.863 | 93.054 | 1.00 | 39.54 | B | C |
| ATOM | 493 | C | GLY | B | 171 | 17.866 | 49.968 | 93.537 | 1.00 | 41.82 | B | C |
| ATOM | 494 | O | GLY | B | 171 | 18.183 | 49.583 | 94.663 | 1.00 | 42.71 | B | O |
| ATOM | 495 | N | THR | B | 172 | 18.739 | 50.484 | 92.682 | 1.00 | 42.71 | B | N |
| ATOM | 496 | CA | THR | B | 172 | 20.139 | 50.643 | 93.043 | 1.00 | 45.37 | B | C |
| ATOM | 497 | CB | THR | B | 172 | 21.073 | 49.941 | 92.028 | 1.00 | 45.41 | B | C |
| ATOM | 498 | OG1 | THR | B | 172 | 21.815 | 50.924 | 91.299 | 1.00 | 47.34 | B | O |
| ATOM | 499 | CG2 | THR | B | 172 | 20.272 | 49.090 | 91.057 | 1.00 | 46.75 | B | C |
| ATOM | 500 | C | THR | B | 172 | 20.493 | 52.123 | 93.112 | 1.00 | 47.04 | B | C |
| ATOM | 501 | O | THR | B | 172 | 19.754 | 52.968 | 92.612 | 1.00 | 47.21 | B | O |
| ATOM | 502 | N | ALA | B | 173 | 21.621 | 52.431 | 93.744 | 1.00 | 49.54 | B | N |
| ATOM | 503 | CA | ALA | B | 173 | 22.068 | 53.812 | 93.883 | 1.00 | 51.57 | B | C |
| ATOM | 504 | CB | ALA | B | 173 | 22.864 | 53.978 | 95.174 | 1.00 | 51.58 | B | C |
| ATOM | 505 | C | ALA | B | 173 | 22.918 | 54.210 | 92.684 | 1.00 | 52.57 | B | C |
| ATOM | 506 | O | ALA | B | 173 | 23.698 | 53.406 | 92.168 | 1.00 | 53.52 | B | O |
| ATOM | 507 | N | TRP | B | 174 | 22.767 | 55.453 | 92.242 | 1.00 | 53.52 | B | N |
| ATOM | 508 | CA | TRP | B | 174 | 23.520 | 55.932 | 91.093 | 1.00 | 53.99 | B | C |
| ATOM | 509 | CB | TRP | B | 174 | 22.887 | 57.208 | 90.530 | 1.00 | 52.12 | B | C |
| ATOM | 510 | CG | TRP | B | 174 | 23.591 | 57.719 | 89.307 | 1.00 | 49.85 | B | C |
| ATOM | 511 | CD2 | TRP | B | 174 | 24.420 | 58.883 | 89.222 | 1.00 | 49.49 | B | C |
| ATOM | 512 | CE2 | TRP | B | 174 | 24.897 | 58.961 | 87.893 | 1.00 | 49.30 | B | C |
| ATOM | 513 | CE3 | TRP | B | 174 | 24.809 | 59.871 | 90.142 | 1.00 | 48.10 | B | C |
| ATOM | 514 | CD1 | TRP | B | 174 | 23.596 | 57.153 | 88.061 | 1.00 | 48.91 | B | C |
| ATOM | 515 | NE1 | TRP | B | 174 | 24.377 | 57.892 | 87.208 | 1.00 | 48.19 | B | N |
| ATOM | 516 | CZ2 | TRP | B | 174 | 25.744 | 59.989 | 87.458 | 1.00 | 49.40 | B | C |
| ATOM | 517 | CZ3 | TRP | B | 174 | 25.652 | 60.893 | 89.711 | 1.00 | 48.15 | B | C |
| ATOM | 518 | CH2 | TRP | B | 174 | 26.110 | 60.943 | 88.378 | 1.00 | 49.22 | B | C |
| ATOM | 519 | C | TRP | B | 174 | 24.986 | 56.188 | 91.417 | 1.00 | 55.05 | B | C |
| ATOM | 520 | O | TRP | B | 174 | 25.314 | 56.912 | 92.360 | 1.00 | 55.49 | B | O |
| ATOM | 521 | N | LYS | B | 175 | 25.858 | 55.588 | 90.611 | 1.00 | 56.49 | B | N |
| ATOM | 522 | CA | LYS | B | 175 | 27.304 | 55.717 | 90.765 | 1.00 | 57.78 | B | C |
| ATOM | 523 | CB | LYS | B | 175 | 27.995 | 54.485 | 90.182 | 1.00 | 59.83 | B | C |
| ATOM | 524 | CG | LYS | B | 175 | 27.274 | 53.882 | 88.978 | 1.00 | 60.69 | B | C |
| ATOM | 525 | CD | LYS | B | 175 | 27.882 | 52.541 | 88.586 | 1.00 | 62.65 | B | C |
| ATOM | 526 | CE | LYS | B | 175 | 27.919 | 51.568 | 89.770 | 1.00 | 64.68 | B | C |
| ATOM | 527 | NZ | LYS | B | 175 | 29.299 | 51.382 | 90.320 | 1.00 | 64.54 | B | N |
| ATOM | 528 | C | LYS | B | 175 | 27.837 | 56.967 | 90.067 | 1.00 | 57.66 | B | C |
| ATOM | 529 | O | LYS | B | 175 | 27.415 | 58.085 | 90.367 | 1.00 | 57.95 | B | O |
| ATOM | 530 | N | ALA | B | 176 | 28.773 | 56.762 | 89.142 | 1.00 | 57.24 | B | N |
| ATOM | 531 | CA | ALA | B | 176 | 29.387 | 57.845 | 88.378 | 1.00 | 57.33 | B | C |
| ATOM | 532 | CB | ALA | B | 176 | 29.824 | 58.972 | 89.308 | 1.00 | 56.94 | B | C |
| ATOM | 533 | C | ALA | B | 176 | 30.590 | 57.312 | 87.608 | 1.00 | 57.92 | B | C |
| ATOM | 534 | O | ALA | B | 176 | 31.461 | 58.079 | 87.191 | 1.00 | 58.58 | B | O |
| ATOM | 535 | N | ASN | B | 177 | 30.634 | 55.994 | 87.426 | 1.00 | 58.56 | B | N |
| ATOM | 536 | CA | ASN | B | 177 | 31.728 | 55.339 | 86.707 | 1.00 | 58.50 | B | C |
| ATOM | 537 | CB | ASN | B | 177 | 31.330 | 53.905 | 86.341 | 1.00 | 59.01 | B | C |
| ATOM | 538 | CG | ASN | B | 177 | 30.179 | 53.848 | 85.347 | 1.00 | 60.66 | B | C |
| ATOM | 539 | OD1 | ASN | B | 177 | 29.329 | 54.738 | 85.312 | 1.00 | 62.39 | B | O |
| ATOM | 540 | ND2 | ASN | B | 177 | 30.148 | 52.797 | 84.533 | 1.00 | 60.76 | B | N |
| ATOM | 541 | C | ASN | B | 177 | 32.126 | 56.098 | 85.440 | 1.00 | 57.25 | B | C |
| ATOM | 542 | O | ASN | B | 177 | 31.302 | 56.317 | 84.548 | 1.00 | 56.65 | B | O |
| ATOM | 543 | N | GLU | B | 178 | 33.391 | 56.499 | 85.366 | 1.00 | 56.05 | B | N |
| ATOM | 544 | CA | GLU | B | 178 | 33.886 | 57.224 | 84.202 | 1.00 | 56.23 | B | C |
| ATOM | 545 | CB | GLU | B | 178 | 34.582 | 58.514 | 84.647 | 1.00 | 58.12 | B | C |
| ATOM | 546 | CG | GLU | B | 178 | 33.626 | 59.587 | 85.170 | 1.00 | 61.10 | B | C |
| ATOM | 547 | CD | GLU | B | 178 | 32.652 | 60.098 | 84.106 | 1.00 | 62.71 | B | C |
| ATOM | 548 | OE1 | GLU | B | 178 | 31.845 | 59.294 | 83.588 | 1.00 | 63.07 | B | O |
| ATOM | 549 | OE2 | GLU | B | 178 | 32.691 | 61.309 | 83.791 | 1.00 | 63.95 | B | O |
| ATOM | 550 | C | GLU | B | 178 | 34.840 | 56.368 | 83.359 | 1.00 | 54.59 | B | C |
| ATOM | 551 | O | GLU | B | 178 | 35.547 | 56.877 | 82.482 | 1.00 | 54.43 | B | O |
| ATOM | 552 | N | SER | B | 179 | 34.841 | 55.063 | 83.623 | 1.00 | 51.87 | B | N |
| ATOM | 553 | CA | SER | B | 179 | 35.696 | 54.122 | 82.904 | 1.00 | 48.99 | B | C |
| ATOM | 554 | CB | SER | B | 179 | 35.706 | 52.771 | 83.625 | 1.00 | 48.53 | B | C |
| ATOM | 555 | OG | SER | B | 179 | 34.618 | 52.659 | 84.524 | 1.00 | 47.69 | B | O |
| ATOM | 556 | C | SER | B | 179 | 35.274 | 53.910 | 81.447 | 1.00 | 46.90 | B | C |
| ATOM | 557 | O | SER | B | 179 | 36.120 | 53.653 | 80.587 | 1.00 | 46.60 | B | O |
| ATOM | 558 | N | SER | B | 180 | 33.972 | 54.013 | 81.178 | 1.00 | 44.45 | B | N |
| ATOM | 559 | CA | SER | B | 180 | 33.443 | 53.822 | 79.828 | 1.00 | 42.93 | B | C |
| ATOM | 560 | CB | SER | B | 180 | 32.096 | 53.102 | 79.887 | 1.00 | 42.80 | B | C |
| ATOM | 561 | OG | SER | B | 180 | 32.003 | 52.301 | 81.052 | 1.00 | 43.39 | B | O |
| ATOM | 562 | C | SER | B | 180 | 33.280 | 55.145 | 79.092 | 1.00 | 41.73 | B | C |
| ATOM | 563 | O | SER | B | 180 | 32.531 | 55.245 | 78.124 | 1.00 | 41.39 | B | O |
| ATOM | 564 | N | TYR | B | 181 | 33.994 | 56.156 | 79.566 | 1.00 | 40.93 | B | N |
| ATOM | 565 | CA | TYR | B | 181 | 33.955 | 57.485 | 78.981 | 1.00 | 40.80 | B | C |
| ATOM | 566 | CB | TYR | B | 181 | 34.483 | 58.498 | 79.996 | 1.00 | 45.50 | B | C |
| ATOM | 567 | CG | TYR | B | 181 | 33.561 | 59.660 | 80.269 | 1.00 | 51.16 | B | C |
| ATOM | 568 | CD1 | TYR | B | 181 | 33.984 | 60.974 | 80.053 | 1.00 | 53.29 | B | C |
| ATOM | 569 | CE1 | TYR | B | 181 | 33.144 | 62.058 | 80.318 | 1.00 | 56.64 | B | C |
| ATOM | 570 | CD2 | TYR | B | 181 | 32.272 | 59.453 | 80.758 | 1.00 | 53.85 | B | C |
| ATOM | 571 | CE2 | TYR | B | 181 | 31.420 | 60.532 | 81.028 | 1.00 | 56.96 | B | C |
| ATOM | 572 | CZ | TYR | B | 181 | 31.863 | 61.830 | 80.807 | 1.00 | 57.90 | B | C |
| ATOM | 573 | OH | TYR | B | 181 | 31.026 | 62.897 | 81.073 | 1.00 | 60.39 | B | O |
| ATOM | 574 | C | TYR | B | 181 | 34.825 | 57.525 | 77.730 | 1.00 | 38.49 | B | C |
| ATOM | 575 | O | TYR | B | 181 | 35.936 | 56.998 | 77.730 | 1.00 | 37.67 | B | O |
| ATOM | 576 | N | PRO | B | 182 | 34.330 | 58.141 | 76.640 | 1.00 | 36.36 | B | N |
| ATOM | 577 | CD | PRO | B | 182 | 33.014 | 58.782 | 76.472 | 1.00 | 34.83 | B | C |
| ATOM | 578 | CA | PRO | B | 182 | 35.137 | 58.208 | 75.415 | 1.00 | 35.48 | B | C |
| ATOM | 579 | CB | PRO | B | 182 | 34.238 | 58.947 | 74.420 | 1.00 | 34.19 | B | C |
| ATOM | 580 | CG | PRO | B | 182 | 33.196 | 59.620 | 75.248 | 1.00 | 33.53 | B | C |
| ATOM | 581 | C | PRO | B | 182 | 36.436 | 58.958 | 75.689 | 1.00 | 35.13 | B | C |
| ATOM | 582 | O | PRO | B | 182 | 36.478 | 59.811 | 76.573 | 1.00 | 37.07 | B | O |
| ATOM | 583 | N | VAL | B | 183 | 37.493 | 58.636 | 74.946 | 1.00 | 33.36 | B | N |
| ATOM | 584 | CA | VAL | B | 183 | 38.783 | 59.291 | 75.137 | 1.00 | 31.61 | B | C |
| ATOM | 585 | CB | VAL | B | 183 | 39.895 | 58.252 | 75.394 | 1.00 | 31.89 | B | C |
| ATOM | 586 | CG1 | VAL | B | 183 | 41.176 | 58.947 | 75.810 | 1.00 | 31.88 | B | C |
| ATOM | 587 | CG2 | VAL | B | 183 | 39.456 | 57.285 | 76.462 | 1.00 | 31.61 | B | C |
| ATOM | 588 | C | VAL | B | 183 | 39.193 | 60.158 | 73.949 | 1.00 | 31.32 | B | C |
| ATOM | 589 | O | VAL | B | 183 | 39.682 | 59.656 | 72.942 | 1.00 | 30.01 | B | O |
| ATOM | 590 | N | PHE | B | 184 | 38.987 | 61.464 | 74.074 | 1.00 | 32.43 | B | N |
| ATOM | 591 | CA | PHE | B | 184 | 39.347 | 62.403 | 73.022 | 1.00 | 34.54 | B | C |
| ATOM | 592 | CB | PHE | B | 184 | 38.494 | 63.668 | 73.122 | 1.00 | 39.04 | B | C |
| ATOM | 593 | CG | PHE | B | 184 | 37.043 | 63.446 | 72.808 | 1.00 | 43.43 | B | C |
| ATOM | 594 | CD1 | PHE | B | 184 | 36.483 | 63.963 | 71.642 | 1.00 | 45.36 | B | C |
| ATOM | 595 | CD2 | PHE | B | 184 | 36.233 | 62.717 | 73.676 | 1.00 | 44.81 | B | C |
| ATOM | 596 | CE1 | PHE | B | 184 | 35.132 | 63.756 | 71.344 | 1.00 | 47.03 | B | C |
| ATOM | 597 | CE2 | PHE | B | 184 | 34.883 | 62.503 | 73.389 | 1.00 | 46.24 | B | C |
| ATOM | 598 | CZ | PHE | B | 184 | 34.332 | 63.025 | 72.220 | 1.00 | 46.73 | B | C |
| ATOM | 599 | C | PHE | B | 184 | 40.809 | 62.757 | 73.218 | 1.00 | 33.87 | B | C |
| ATOM | 600 | O | PHE | B | 184 | 41.251 | 62.937 | 74.349 | 1.00 | 34.29 | B | O |
| ATOM | 601 | N | THR | B | 185 | 41.573 | 62.848 | 72.137 | 1.00 | 33.56 | B | N |
| ATOM | 602 | CA | THR | B | 185 | 42.977 | 63.179 | 72.302 | 1.00 | 33.95 | B | C |
| ATOM | 603 | CB | THR | B | 185 | 43.783 | 62.996 | 70.977 | 1.00 | 31.95 | B | C |
| ATOM | 604 | OG1 | THR | B | 185 | 44.400 | 64.231 | 70.602 | 1.00 | 32.22 | B | O |
| ATOM | 605 | CG2 | THR | B | 185 | 42.888 | 62.497 | 69.874 | 1.00 | 32.73 | B | C |
| ATOM | 606 | C | THR | B | 185 | 43.088 | 64.605 | 72.845 | 1.00 | 34.12 | B | C |
| ATOM | 607 | O | THR | B | 185 | 42.374 | 65.508 | 72.410 | 1.00 | 34.39 | B | O |
| ATOM | 608 | N | PRO | B | 186 | 43.967 | 64.811 | 73.839 | 1.00 | 34.64 | B | N |
| ATOM | 609 | CD | PRO | B | 186 | 44.822 | 63.773 | 74.439 | 1.00 | 33.51 | B | C |
| ATOM | 610 | CA | PRO | B | 186 | 44.186 | 66.116 | 74.470 | 1.00 | 34.49 | B | C |
| ATOM | 611 | CB | PRO | B | 186 | 45.339 | 65.863 | 75.446 | 1.00 | 34.80 | B | C |
| ATOM | 612 | CG | PRO | B | 186 | 45.942 | 64.569 | 75.018 | 1.00 | 35.43 | B | C |
| ATOM | 613 | C | PRO | B | 186 | 44.502 | 67.250 | 73.514 | 1.00 | 35.42 | B | C |
| ATOM | 614 | O | PRO | B | 186 | 45.097 | 67.042 | 72.463 | 1.00 | 35.41 | B | O |
| ATOM | 615 | N | ALA | B | 187 | 44.092 | 68.457 | 73.889 | 1.00 | 36.29 | B | N |
| ATOM | 616 | CA | ALA | B | 187 | 44.361 | 69.629 | 73.075 | 1.00 | 38.06 | B | C |
| ATOM | 617 | CB | ALA | B | 187 | 43.703 | 70.858 | 73.693 | 1.00 | 35.93 | B | C |
| ATOM | 618 | C | ALA | B | 187 | 45.873 | 69.790 | 73.070 | 1.00 | 39.27 | B | C |
| ATOM | 619 | O | ALA | B | 187 | 46.537 | 69.421 | 74.036 | 1.00 | 40.11 | B | O |
| ATOM | 620 | N | LEU | B | 188 | 46.434 | 70.315 | 71.989 | 1.00 | 41.98 | B | N |
| ATOM | 621 | CA | LEU | B | 188 | 47.874 | 70.496 | 71.965 | 1.00 | 43.73 | B | C |
| ATOM | 622 | CB | LEU | B | 188 | 48.443 | 70.329 | 70.547 | 1.00 | 43.92 | B | C |
| ATOM | 623 | CG | LEU | B | 188 | 47.668 | 70.768 | 69.310 | 1.00 | 44.94 | B | C |
| ATOM | 624 | CD1 | LEU | B | 188 | 48.521 | 71.752 | 68.509 | 1.00 | 43.23 | B | C |
| ATOM | 625 | CD2 | LEU | B | 188 | 47.321 | 69.541 | 68.466 | 1.00 | 44.29 | B | C |
| ATOM | 626 | C | LEU | B | 188 | 48.217 | 71.870 | 72.518 | 1.00 | 44.57 | B | C |
| ATOM | 627 | O | LEU | B | 188 | 47.490 | 72.836 | 72.294 | 1.00 | 44.13 | B | O |
| ATOM | 628 | N | LYS | B | 189 | 49.314 | 71.942 | 73.264 | 1.00 | 47.13 | B | N |
| ATOM | 629 | CA | LYS | B | 189 | 49.761 | 73.199 | 73.846 | 1.00 | 50.74 | B | C |
| ATOM | 630 | CB | LYS | B | 189 | 51.088 | 72.995 | 74.569 | 1.00 | 49.16 | B | C |
| ATOM | 631 | CG | LYS | B | 189 | 51.118 | 71.747 | 75.437 | 1.00 | 49.62 | B | C |
| ATOM | 632 | CD | LYS | B | 189 | 50.714 | 72.060 | 76.871 | 1.00 | 51.14 | B | C |
| ATOM | 633 | CE | LYS | B | 189 | 49.449 | 71.316 | 77.279 | 1.00 | 51.28 | B | C |
| ATOM | 634 | NZ | LYS | B | 189 | 49.685 | 69.854 | 77.455 | 1.00 | 50.43 | B | N |
| ATOM | 635 | C | LYS | B | 189 | 49.922 | 74.251 | 72.759 | 1.00 | 53.43 | B | C |
| ATOM | 636 | O | LYS | B | 189 | 50.155 | 73.922 | 71.592 | 1.00 | 53.41 | B | O |
| ATOM | 637 | N | LYS | B | 190 | 49.780 | 75.517 | 73.139 | 1.00 | 57.70 | B | N |
| ATOM | 638 | CA | LYS | B | 190 | 49.912 | 76.610 | 72.179 | 1.00 | 60.08 | B | C |
| ATOM | 639 | CB | LYS | B | 190 | 49.856 | 77.963 | 72.899 | 1.00 | 62.07 | B | C |
| ATOM | 640 | CG | LYS | B | 190 | 50.089 | 79.170 | 71.996 | 1.00 | 63.52 | B | C |
| ATOM | 641 | CD | LYS | B | 190 | 51.297 | 79.981 | 72.456 | 1.00 | 65.16 | B | C |
| ATOM | 642 | CE | LYS | B | 190 | 51.189 | 80.377 | 73.928 | 1.00 | 66.36 | B | C |
| ATOM | 643 | NZ | LYS | B | 190 | 52.397 | 79.977 | 74.707 | 1.00 | 68.13 | B | N |
| ATOM | 644 | C | LYS | B | 190 | 51.247 | 76.450 | 71.458 | 1.00 | 60.57 | B | C |
| ATOM | 645 | O | LYS | B | 190 | 52.303 | 76.337 | 72.096 | 1.00 | 59.74 | B | O |
| ATOM | 646 | N | GLY | B | 191 | 51.197 | 76.426 | 70.129 | 1.00 | 60.07 | B | N |
| ATOM | 647 | CA | GLY | B | 191 | 52.421 | 76.261 | 69.371 | 1.00 | 58.76 | B | C |
| ATOM | 648 | C | GLY | B | 191 | 53.103 | 74.953 | 69.740 | 1.00 | 57.74 | B | C |
| ATOM | 649 | O | GLY | B | 191 | 54.083 | 74.926 | 70.493 | 1.00 | 57.22 | B | O |
| ATOM | 650 | N | GLU | B | 192 | 52.558 | 73.859 | 69.223 | 1.00 | 55.26 | B | N |
| ATOM | 651 | CA | GLU | B | 192 | 53.106 | 72.533 | 69.468 | 1.00 | 51.43 | B | C |
| ATOM | 652 | CB | GLU | B | 192 | 52.347 | 71.836 | 70.597 | 1.00 | 49.33 | B | C |
| ATOM | 653 | CG | GLU | B | 192 | 52.943 | 70.496 | 70.997 | 1.00 | 47.34 | B | C |
| ATOM | 654 | CD | GLU | B | 192 | 51.977 | 69.630 | 71.798 | 1.00 | 47.25 | B | C |
| ATOM | 655 | OE1 | GLU | B | 192 | 52.290 | 68.445 | 72.040 | 1.00 | 44.68 | B | O |
| ATOM | 656 | OE2 | GLU | B | 192 | 50.904 | 70.131 | 72.191 | 1.00 | 47.14 | B | O |
| ATOM | 657 | C | GLU | B | 192 | 52.961 | 71.742 | 68.176 | 1.00 | 50.12 | B | C |
| ATOM | 658 | O | GLU | B | 192 | 52.029 | 71.978 | 67.399 | 1.00 | 51.90 | B | O |
| ATOM | 659 | N | ASP | B | 193 | 53.883 | 70.813 | 67.946 | 1.00 | 46.50 | B | N |
| ATOM | 660 | CA | ASP | B | 193 | 53.860 | 69.990 | 66.739 | 1.00 | 42.77 | B | C |
| ATOM | 661 | CB | ASP | B | 193 | 55.160 | 69.196 | 66.627 | 1.00 | 42.80 | B | C |
| ATOM | 662 | CG | ASP | B | 193 | 55.353 | 68.581 | 65.257 | 1.00 | 43.49 | B | C |
| ATOM | 663 | OD1 | ASP | B | 193 | 55.761 | 67.403 | 65.191 | 1.00 | 45.00 | B | O |
| ATOM | 664 | OD2 | ASP | B | 193 | 55.103 | 69.271 | 64.247 | 1.00 | 45.23 | B | O |
| ATOM | 665 | C | ASP | B | 193 | 52.669 | 69.037 | 66.755 | 1.00 | 38.94 | B | C |
| ATOM | 666 | O | ASP | B | 193 | 52.589 | 68.144 | 67.597 | 1.00 | 37.98 | B | O |
| ATOM | 667 | N | PRO | B | 194 | 51.725 | 69.217 | 65.818 | 1.00 | 35.80 | B | N |
| ATOM | 668 | CD | PRO | B | 194 | 51.699 | 70.227 | 64.750 | 1.00 | 34.64 | B | C |
| ATOM | 669 | CA | PRO | B | 194 | 50.552 | 68.341 | 65.774 | 1.00 | 33.02 | B | C |
| ATOM | 670 | CB | PRO | B | 194 | 49.580 | 69.070 | 64.840 | 1.00 | 32.45 | B | C |
| ATOM | 671 | CG | PRO | B | 194 | 50.244 | 70.372 | 64.474 | 1.00 | 34.44 | B | C |
| ATOM | 672 | C | PRO | B | 194 | 50.903 | 66.960 | 65.246 | 1.00 | 32.44 | B | C |
| ATOM | 673 | O | PRO | B | 194 | 50.099 | 66.032 | 65.326 | 1.00 | 32.30 | B | O |
| ATOM | 674 | N | PHE | B | 195 | 52.113 | 66.823 | 64.720 | 1.00 | 31.66 | B | N |
| ATOM | 675 | CA | PHE | B | 195 | 52.543 | 65.557 | 64.146 | 1.00 | 33.24 | B | C |
| ATOM | 676 | CB | PHE | B | 195 | 52.867 | 65.763 | 62.664 | 1.00 | 30.85 | B | C |
| ATOM | 677 | CG | PHE | B | 195 | 51.822 | 66.558 | 61.930 | 1.00 | 28.21 | B | C |
| ATOM | 678 | CD1 | PHE | B | 195 | 50.643 | 65.952 | 61.501 | 1.00 | 27.75 | B | C |
| ATOM | 679 | CD2 | PHE | B | 195 | 51.998 | 67.917 | 61.700 | 1.00 | 26.12 | B | C |
| ATOM | 680 | CE1 | PHE | B | 195 | 49.654 | 66.692 | 60.857 | 1.00 | 25.08 | B | C |
| ATOM | 681 | CE2 | PHE | B | 195 | 51.017 | 68.661 | 61.059 | 1.00 | 25.80 | B | C |
| ATOM | 682 | CZ | PHE | B | 195 | 49.843 | 68.047 | 60.638 | 1.00 | 25.79 | B | C |
| ATOM | 683 | C | PHE | B | 195 | 53.716 | 64.897 | 64.854 | 1.00 | 35.38 | B | C |
| ATOM | 684 | O | PHE | B | 195 | 54.469 | 64.141 | 64.236 | 1.00 | 34.66 | B | O |
| ATOM | 685 | N | ARG | B | 196 | 53.853 | 65.170 | 66.151 | 1.00 | 37.46 | B | N |
| ATOM | 686 | CA | ARG | B | 196 | 54.927 | 64.598 | 66.964 | 1.00 | 38.90 | B | C |
| ATOM | 687 | CB | ARG | B | 196 | 54.797 | 65.053 | 68.419 | 1.00 | 40.86 | B | C |
| ATOM | 688 | CG | ARG | B | 196 | 54.896 | 66.553 | 68.602 | 1.00 | 45.40 | B | C |
| ATOM | 689 | CD | ARG | B | 196 | 54.836 | 66.933 | 70.067 | 1.00 | 48.62 | B | C |
| ATOM | 690 | NE | ARG | B | 196 | 55.772 | 66.152 | 70.871 | 1.00 | 51.28 | B | N |
| ATOM | 691 | CZ | ARG | B | 196 | 56.154 | 66.483 | 72.101 | 1.00 | 53.01 | B | C |
| ATOM | 692 | NH1 | ARG | B | 196 | 55.681 | 67.583 | 72.674 | 1.00 | 52.10 | B | N |
| ATOM | 693 | NH2 | ARG | B | 196 | 57.013 | 65.715 | 72.759 | 1.00 | 53.70 | B | N |
| ATOM | 694 | C | ARG | B | 196 | 54.894 | 63.079 | 66.916 | 1.00 | 38.76 | B | C |
| ATOM | 695 | O | ARG | B | 196 | 53.828 | 62.469 | 66.929 | 1.00 | 38.68 | B | O |
| ATOM | 696 | N | THR | B | 197 | 56.068 | 62.466 | 66.881 | 1.00 | 39.50 | B | N |
| ATOM | 697 | CA | THR | B | 197 | 56.146 | 61.016 | 66.822 | 1.00 | 40.88 | B | C |
| ATOM | 698 | CB | THR | B | 197 | 56.617 | 60.568 | 65.422 | 1.00 | 40.79 | B | C |
| ATOM | 699 | OG1 | THR | B | 197 | 56.252 | 59.200 | 65.209 | 1.00 | 42.29 | B | O |
| ATOM | 700 | CG2 | THR | B | 197 | 58.123 | 60.734 | 65.281 | 1.00 | 39.25 | B | C |
| ATOM | 701 | C | THR | B | 197 | 57.078 | 60.441 | 67.892 | 1.00 | 41.70 | B | C |
| ATOM | 702 | O | THR | B | 197 | 57.483 | 59.279 | 67.819 | 1.00 | 42.24 | B | O |
| ATOM | 703 | N | ASP | B | 198 | 57.403 | 61.255 | 68.893 | 1.00 | 41.85 | B | N |
| ATOM | 704 | CA | ASP | B | 198 | 58.292 | 60.826 | 69.962 | 1.00 | 41.79 | B | C |
| ATOM | 705 | CB | ASP | B | 198 | 59.210 | 61.978 | 70.377 | 1.00 | 41.84 | B | C |
| ATOM | 706 | CG | ASP | B | 198 | 58.446 | 63.205 | 70.835 | 1.00 | 43.07 | B | C |
| ATOM | 707 | OD1 | ASP | B | 198 | 57.779 | 63.844 | 69.997 | 1.00 | 44.38 | B | O |
| ATOM | 708 | OD2 | ASP | B | 198 | 58.518 | 63.538 | 72.036 | 1.00 | 44.52 | B | O |
| ATOM | 709 | C | ASP | B | 198 | 57.566 | 60.290 | 71.189 | 1.00 | 42.52 | B | C |
| ATOM | 710 | O | ASP | B | 198 | 58.190 | 59.722 | 72.084 | 1.00 | 43.69 | B | O |
| ATOM | 711 | N | ASN | B | 199 | 56.249 | 60.452 | 71.227 | 1.00 | 42.53 | B | N |
| ATOM | 712 | CA | ASN | B | 199 | 55.468 | 59.996 | 72.369 | 1.00 | 41.60 | B | C |
| ATOM | 713 | CB | ASN | B | 199 | 54.618 | 61.151 | 72.891 | 1.00 | 45.19 | B | C |
| ATOM | 714 | CG | ASN | B | 199 | 54.050 | 62.003 | 71.767 | 1.00 | 49.49 | B | C |
| ATOM | 715 | OD1 | ASN | B | 199 | 53.874 | 63.215 | 71.917 | 1.00 | 52.42 | B | O |
| ATOM | 716 | ND2 | ASN | B | 199 | 53.761 | 61.370 | 70.627 | 1.00 | 49.40 | B | N |
| ATOM | 717 | C | ASN | B | 199 | 54.573 | 58.802 | 72.046 | 1.00 | 39.45 | B | C |
| ATOM | 718 | O | ASN | B | 199 | 53.587 | 58.554 | 72.738 | 1.00 | 39.08 | B | O |
| ATOM | 719 | N | LEU | B | 200 | 54.923 | 58.058 | 71.003 | 1.00 | 36.92 | B | N |
| ATOM | 720 | CA | LEU | B | 200 | 54.140 | 56.895 | 70.601 | 1.00 | 34.24 | B | C |
| ATOM | 721 | CB | LEU | B | 200 | 54.381 | 56.576 | 69.125 | 1.00 | 33.90 | B | C |
| ATOM | 722 | CG | LEU | B | 200 | 53.771 | 57.471 | 68.047 | 1.00 | 35.28 | B | C |
| ATOM | 723 | CD1 | LEU | B | 200 | 54.143 | 56.915 | 66.680 | 1.00 | 35.11 | B | C |
| ATOM | 724 | CD2 | LEU | B | 200 | 52.259 | 57.530 | 68.200 | 1.00 | 33.80 | B | C |
| ATOM | 725 | C | LEU | B | 200 | 54.492 | 55.665 | 71.426 | 1.00 | 33.78 | B | C |
| ATOM | 726 | O | LEU | B | 200 | 55.658 | 55.436 | 71.749 | 1.00 | 34.01 | B | O |
| ATOM | 727 | N | PRO | B | 201 | 53.483 | 54.851 | 71.777 | 1.00 | 33.33 | B | N |
| ATOM | 728 | CD | PRO | B | 201 | 52.061 | 55.060 | 71.463 | 1.00 | 31.63 | B | C |
| ATOM | 729 | CA | PRO | B | 201 | 53.685 | 53.628 | 72.566 | 1.00 | 34.65 | B | C |
| ATOM | 730 | CB | PRO | B | 201 | 52.275 | 53.060 | 72.728 | 1.00 | 32.15 | B | C |
| ATOM | 731 | CG | PRO | B | 201 | 51.368 | 54.195 | 72.459 | 1.00 | 29.83 | B | C |
| ATOM | 732 | C | PRO | B | 201 | 54.619 | 52.629 | 71.880 | 1.00 | 36.31 | B | C |
| ATOM | 733 | O | PRO | B | 201 | 55.057 | 52.845 | 70.750 | 1.00 | 37.00 | B | O |
| ATOM | 734 | N | GLU | B | 202 | 54.912 | 51.533 | 72.570 | 1.00 | 37.96 | B | N |
| ATOM | 735 | CA | GLU | B | 202 | 55.787 | 50.501 | 72.029 | 1.00 | 40.97 | B | C |
| ATOM | 736 | CB | GLU | B | 202 | 56.599 | 49.846 | 73.152 | 1.00 | 45.07 | B | C |
| ATOM | 737 | CG | GLU | B | 202 | 56.874 | 50.752 | 74.349 | 1.00 | 53.09 | B | C |
| ATOM | 738 | CD | GLU | B | 202 | 57.602 | 50.031 | 75.483 | 1.00 | 57.96 | B | C |
| ATOM | 739 | OE1 | GLU | B | 202 | 57.207 | 48.888 | 75.823 | 1.00 | 59.91 | B | O |
| ATOM | 740 | OE2 | GLU | B | 202 | 58.568 | 50.611 | 76.036 | 1.00 | 60.42 | B | O |
| ATOM | 741 | C | GLU | B | 202 | 54.959 | 49.439 | 71.320 | 1.00 | 39.13 | B | C |
| ATOM | 742 | O | GLU | B | 202 | 53.763 | 49.308 | 71.568 | 1.00 | 39.22 | B | O |
| ATOM | 743 | N | ASN | B | 203 | 55.595 | 48.678 | 70.439 | 1.00 | 37.75 | B | N |
| ATOM | 744 | CA | ASN | B | 203 | 54.892 | 47.631 | 69.708 | 1.00 | 36.99 | B | C |
| ATOM | 745 | CB | ASN | B | 203 | 55.735 | 47.156 | 68.525 | 1.00 | 36.13 | B | C |
| ATOM | 746 | CG | ASN | B | 203 | 55.991 | 48.255 | 67.509 | 1.00 | 36.06 | B | C |
| ATOM | 747 | OD1 | ASN | B | 203 | 56.765 | 48.077 | 66.570 | 1.00 | 37.95 | B | O |
| ATOM | 748 | ND2 | ASN | B | 203 | 55.343 | 49.397 | 67.692 | 1.00 | 35.66 | B | N |
| ATOM | 749 | C | ASN | B | 203 | 54.586 | 46.461 | 70.635 | 1.00 | 36.81 | B | C |
| ATOM | 750 | O | ASN | B | 203 | 55.371 | 46.146 | 71.528 | 1.00 | 38.24 | B | O |
| ATOM | 751 | N | LEU | B | 204 | 53.443 | 45.819 | 70.423 | 1.00 | 36.53 | B | N |
| ATOM | 752 | CA | LEU | B | 204 | 53.032 | 44.690 | 71.254 | 1.00 | 36.65 | B | C |
| ATOM | 753 | CB | LEU | B | 204 | 51.641 | 44.941 | 71.839 | 1.00 | 36.86 | B | C |
| ATOM | 754 | CG | LEU | B | 204 | 51.472 | 46.186 | 72.711 | 1.00 | 37.91 | B | C |
| ATOM | 755 | CD1 | LEU | B | 204 | 50.005 | 46.353 | 73.059 | 1.00 | 38.35 | B | C |
| ATOM | 756 | CD2 | LEU | B | 204 | 52.314 | 46.053 | 73.972 | 1.00 | 37.10 | B | C |
| ATOM | 757 | C | LEU | B | 204 | 53.019 | 43.377 | 70.489 | 1.00 | 35.88 | B | C |
| ATOM | 758 | O | LEU | B | 204 | 52.724 | 42.330 | 71.052 | 1.00 | 37.66 | B | O |
| ATOM | 759 | N | GLY | B | 205 | 53.324 | 43.446 | 69.200 | 1.00 | 36.09 | B | N |
| ATOM | 760 | CA | GLY | B | 205 | 53.360 | 42.255 | 68.375 | 1.00 | 34.77 | B | C |
| ATOM | 761 | C | GLY | B | 205 | 52.270 | 41.216 | 68.561 | 1.00 | 34.26 | B | C |
| ATOM | 762 | O | GLY | B | 205 | 52.540 | 40.023 | 68.428 | 1.00 | 34.79 | B | O |
| ATOM | 763 | N | TYR | B | 206 | 51.046 | 41.637 | 68.866 | 1.00 | 33.81 | B | N |
| ATOM | 764 | CA | TYR | B | 206 | 49.958 | 40.669 | 69.022 | 1.00 | 35.18 | B | C |
| ATOM | 765 | CB | TYR | B | 206 | 48.729 | 41.311 | 69.671 | 1.00 | 37.83 | B | C |
| ATOM | 766 | CG | TYR | B | 206 | 48.900 | 41.699 | 71.117 | 1.00 | 40.66 | B | C |
| ATOM | 767 | CD1 | TYR | B | 206 | 49.678 | 40.929 | 71.983 | 1.00 | 42.63 | B | C |
| ATOM | 768 | CE1 | TYR | B | 206 | 49.830 | 41.284 | 73.324 | 1.00 | 43.40 | B | C |
| ATOM | 769 | CD2 | TYR | B | 206 | 48.275 | 42.834 | 71.625 | 1.00 | 41.68 | B | C |
| ATOM | 770 | CE2 | TYR | B | 206 | 48.418 | 43.198 | 72.960 | 1.00 | 43.13 | B | C |
| ATOM | 771 | CZ | TYR | B | 206 | 49.196 | 42.420 | 73.804 | 1.00 | 43.96 | B | C |
| ATOM | 772 | OH | TYR | B | 206 | 49.344 | 42.787 | 75.121 | 1.00 | 46.61 | B | O |
| ATOM | 773 | C | TYR | B | 206 | 49.567 | 40.171 | 67.635 | 1.00 | 35.23 | B | C |
| ATOM | 774 | O | TYR | B | 206 | 49.982 | 40.741 | 66.626 | 1.00 | 34.23 | B | O |
| ATOM | 775 | N | HIS | B | 207 | 48.768 | 39.113 | 67.580 | 1.00 | 34.50 | B | N |
| ATOM | 776 | CA | HIS | B | 207 | 48.335 | 38.589 | 66.298 | 1.00 | 35.12 | B | C |
| ATOM | 777 | CB | HIS | B | 207 | 48.477 | 37.066 | 66.262 | 1.00 | 38.37 | B | C |
| ATOM | 778 | CG | HIS | B | 207 | 48.277 | 36.479 | 64.898 | 1.00 | 41.59 | B | C |
| ATOM | 779 | CD2 | HIS | B | 207 | 48.997 | 36.607 | 63.759 | 1.00 | 41.85 | B | C |
| ATOM | 780 | ND1 | HIS | B | 207 | 47.206 | 35.666 | 64.585 | 1.00 | 43.85 | B | N |
| ATOM | 781 | CE1 | HIS | B | 207 | 47.276 | 35.320 | 63.312 | 1.00 | 43.11 | B | C |
| ATOM | 782 | NE2 | HIS | B | 207 | 48.353 | 35.878 | 62.788 | 1.00 | 43.03 | B | N |
| ATOM | 783 | C | HIS | B | 207 | 46.885 | 38.982 | 66.029 | 1.00 | 34.49 | B | C |
| ATOM | 784 | O | HIS | B | 207 | 45.985 | 38.640 | 66.797 | 1.00 | 33.72 | B | O |
| ATOM | 785 | N | LEU | B | 208 | 46.667 | 39.704 | 64.932 | 1.00 | 33.96 | B | N |
| ATOM | 786 | CA | LEU | B | 208 | 45.331 | 40.148 | 64.556 | 1.00 | 33.18 | B | C |
| ATOM | 787 | CB | LEU | B | 208 | 45.396 | 41.554 | 63.967 | 1.00 | 31.07 | B | C |
| ATOM | 788 | CG | LEU | B | 208 | 45.969 | 42.597 | 64.928 | 1.00 | 30.64 | B | C |
| ATOM | 789 | CD1 | LEU | B | 208 | 46.244 | 43.889 | 64.179 | 1.00 | 31.15 | B | C |
| ATOM | 790 | CD2 | LEU | B | 208 | 44.994 | 42.829 | 66.072 | 1.00 | 29.33 | B | C |
| ATOM | 791 | C | LEU | B | 208 | 44.702 | 39.188 | 63.556 | 1.00 | 33.68 | B | C |
| ATOM | 792 | O | LEU | B | 208 | 45.350 | 38.740 | 62.615 | 1.00 | 33.49 | B | O |
| ATOM | 793 | N | LYS | B | 209 | 43.433 | 38.873 | 63.766 | 1.00 | 34.32 | B | N |
| ATOM | 794 | CA | LYS | B | 209 | 42.730 | 37.950 | 62.890 | 1.00 | 35.37 | B | C |
| ATOM | 795 | CB | LYS | B | 209 | 42.899 | 36.518 | 63.404 | 1.00 | 37.46 | B | C |
| ATOM | 796 | CG | LYS | B | 209 | 42.859 | 35.461 | 62.318 | 1.00 | 39.05 | B | C |
| ATOM | 797 | CD | LYS | B | 209 | 42.495 | 34.095 | 62.887 | 1.00 | 42.61 | B | C |
| ATOM | 798 | CE | LYS | B | 209 | 42.109 | 33.124 | 61.778 | 1.00 | 43.40 | B | C |
| ATOM | 799 | NZ | LYS | B | 209 | 42.011 | 31.719 | 62.257 | 1.00 | 44.76 | B | N |
| ATOM | 800 | C | LYS | B | 209 | 41.248 | 38.288 | 62.807 | 1.00 | 34.40 | B | C |
| ATOM | 801 | O | LYS | B | 209 | 40.608 | 38.590 | 63.813 | 1.00 | 34.47 | B | O |
| ATOM | 802 | N | MET | B | 210 | 40.712 | 38.237 | 61.595 | 1.00 | 32.92 | B | N |
| ATOM | 803 | CA | MET | B | 210 | 39.308 | 38.526 | 61.363 | 1.00 | 31.88 | B | C |
| ATOM | 804 | CB | MET | B | 210 | 39.077 | 38.800 | 59.873 | 1.00 | 31.91 | B | C |
| ATOM | 805 | CG | MET | B | 210 | 37.793 | 39.549 | 59.563 | 1.00 | 34.14 | B | C |
| ATOM | 806 | SD | MET | B | 210 | 37.944 | 41.362 | 59.653 | 1.00 | 33.52 | B | S |
| ATOM | 807 | CE | MET | B | 210 | 39.677 | 41.562 | 59.721 | 1.00 | 28.43 | B | C |
| ATOM | 808 | C | MET | B | 210 | 38.475 | 37.328 | 61.806 | 1.00 | 31.89 | B | C |
| ATOM | 809 | O | MET | B | 210 | 38.841 | 36.182 | 61.542 | 1.00 | 31.31 | B | O |
| ATOM | 810 | N | LYS | B | 211 | 37.363 | 37.585 | 62.486 | 1.00 | 31.01 | B | N |
| ATOM | 811 | CA | LYS | B | 211 | 36.497 | 36.504 | 62.939 | 1.00 | 31.46 | B | C |
| ATOM | 812 | CB | LYS | B | 211 | 36.783 | 36.155 | 64.399 | 1.00 | 32.69 | B | C |
| ATOM | 813 | CG | LYS | B | 211 | 36.312 | 34.767 | 64.780 | 1.00 | 33.61 | B | C |
| ATOM | 814 | CD | LYS | B | 211 | 35.503 | 34.803 | 66.052 | 1.00 | 36.86 | B | C |
| ATOM | 815 | CE | LYS | B | 211 | 36.114 | 33.900 | 67.104 | 1.00 | 39.26 | B | C |
| ATOM | 816 | NZ | LYS | B | 211 | 35.878 | 32.471 | 66.761 | 1.00 | 43.71 | B | N |
| ATOM | 817 | C | LYS | B | 211 | 35.029 | 36.866 | 62.780 | 1.00 | 31.63 | B | C |
| ATOM | 818 | O | LYS | B | 211 | 34.486 | 37.671 | 63.540 | 1.00 | 32.70 | B | O |
| ATOM | 819 | N | ASP | B | 212 | 34.393 | 36.258 | 61.784 | 1.00 | 30.26 | B | N |
| ATOM | 820 | CA | ASP | B | 212 | 32.993 | 36.506 | 61.489 | 1.00 | 29.36 | B | C |
| ATOM | 821 | CB | ASP | B | 212 | 32.107 | 35.916 | 62.586 | 1.00 | 32.46 | B | C |
| ATOM | 822 | CG | ASP | B | 212 | 32.074 | 34.399 | 62.559 | 1.00 | 34.01 | B | C |
| ATOM | 823 | OD1 | ASP | B | 212 | 32.132 | 33.814 | 61.458 | 1.00 | 33.96 | B | O |
| ATOM | 824 | OD2 | ASP | B | 212 | 31.989 | 33.791 | 63.646 | 1.00 | 36.60 | B | O |
| ATOM | 825 | C | ASP | B | 212 | 32.705 | 37.997 | 61.329 | 1.00 | 26.99 | B | C |
| ATOM | 826 | O | ASP | B | 212 | 31.672 | 38.489 | 61.766 | 1.00 | 25.56 | B | O |
| ATOM | 827 | N | GLY | B | 213 | 33.632 | 38.711 | 60.701 | 1.00 | 27.21 | B | N |
| ATOM | 828 | CA | GLY | B | 213 | 33.439 | 40.132 | 60.472 | 1.00 | 26.20 | B | C |
| ATOM | 829 | C | GLY | B | 213 | 34.055 | 41.070 | 61.493 | 1.00 | 25.12 | B | C |
| ATOM | 830 | O | GLY | B | 213 | 33.980 | 42.290 | 61.334 | 1.00 | 23.64 | B | O |
| ATOM | 831 | N | VAL | B | 214 | 34.671 | 40.521 | 62.536 | 1.00 | 23.94 | B | N |
| ATOM | 832 | CA | VAL | B | 214 | 35.274 | 41.365 | 63.560 | 1.00 | 24.04 | B | C |
| ATOM | 833 | CB | VAL | B | 214 | 34.534 | 41.217 | 64.922 | 1.00 | 23.42 | B | C |
| ATOM | 834 | CG1 | VAL | B | 214 | 35.076 | 42.226 | 65.930 | 1.00 | 23.13 | B | C |
| ATOM | 835 | CG2 | VAL | B | 214 | 33.041 | 41.427 | 64.729 | 1.00 | 22.60 | B | C |
| ATOM | 836 | C | VAL | B | 214 | 36.743 | 41.044 | 63.766 | 1.00 | 25.05 | B | C |
| ATOM | 837 | O | VAL | B | 214 | 37.131 | 39.877 | 63.781 | 1.00 | 25.67 | B | O |
| ATOM | 838 | N | VAL | B | 215 | 37.562 | 42.081 | 63.912 | 1.00 | 24.32 | B | N |
| ATOM | 839 | CA | VAL | B | 215 | 38.984 | 41.884 | 64.147 | 1.00 | 24.46 | B | C |
| ATOM | 840 | CB | VAL | B | 215 | 39.786 | 43.198 | 63.975 | 1.00 | 23.79 | B | C |
| ATOM | 841 | CG1 | VAL | B | 215 | 41.271 | 42.944 | 64.226 | 1.00 | 22.00 | B | C |
| ATOM | 842 | CG2 | VAL | B | 215 | 39.568 | 43.765 | 62.577 | 1.00 | 23.88 | B | C |
| ATOM | 843 | C | VAL | B | 215 | 39.162 | 41.394 | 65.584 | 1.00 | 26.01 | B | C |
| ATOM | 844 | O | VAL | B | 215 | 38.755 | 42.069 | 66.532 | 1.00 | 25.52 | B | O |
| ATOM | 845 | N | TYR | B | 216 | 39.749 | 40.211 | 65.735 | 1.00 | 26.59 | B | N |
| ATOM | 846 | CA | TYR | B | 216 | 39.997 | 39.642 | 67.051 | 1.00 | 27.11 | B | C |
| ATOM | 847 | CB | TYR | B | 216 | 39.532 | 38.195 | 67.103 | 1.00 | 26.82 | B | C |
| ATOM | 848 | CG | TYR | B | 216 | 38.095 | 38.058 | 67.521 | 1.00 | 28.45 | B | C |
| ATOM | 849 | CD1 | TYR | B | 216 | 37.744 | 37.321 | 68.649 | 1.00 | 28.33 | B | C |
| ATOM | 850 | CE1 | TYR | B | 216 | 36.416 | 37.195 | 69.039 | 1.00 | 28.04 | B | C |
| ATOM | 851 | CD2 | TYR | B | 216 | 37.079 | 38.670 | 66.789 | 1.00 | 29.86 | B | C |
| ATOM | 852 | CE2 | TYR | B | 216 | 35.746 | 38.552 | 67.170 | 1.00 | 28.92 | B | C |
| ATOM | 853 | CZ | TYR | B | 216 | 35.422 | 37.811 | 68.295 | 1.00 | 29.14 | B | C |
| ATOM | 854 | OH | TYR | B | 216 | 34.103 | 37.683 | 68.667 | 1.00 | 29.49 | B | O |
| ATOM | 855 | C | TYR | B | 216 | 41.479 | 39.710 | 67.362 | 1.00 | 28.45 | B | C |
| ATOM | 856 | O | TYR | B | 216 | 42.311 | 39.473 | 66.493 | 1.00 | 27.47 | B | O |
| ATOM | 857 | N | ILE | B | 217 | 41.810 | 40.047 | 68.604 | 1.00 | 31.00 | B | N |
| ATOM | 858 | CA | ILE | B | 217 | 43.204 | 40.143 | 69.007 | 1.00 | 33.79 | B | C |
| ATOM | 859 | CB | ILE | B | 217 | 43.459 | 41.384 | 69.880 | 1.00 | 34.67 | B | C |
| ATOM | 860 | CG2 | ILE | B | 217 | 44.932 | 41.440 | 70.271 | 1.00 | 35.64 | B | C |
| ATOM | 861 | CG1 | ILE | B | 217 | 43.062 | 42.654 | 69.120 | 1.00 | 36.25 | B | C |
| ATOM | 862 | CD1 | ILE | B | 217 | 41.911 | 43.416 | 69.759 | 1.00 | 36.28 | B | C |
| ATOM | 863 | C | ILE | B | 217 | 43.621 | 38.908 | 69.788 | 1.00 | 35.61 | B | C |
| ATOM | 864 | O | ILE | B | 217 | 42.981 | 38.536 | 70.774 | 1.00 | 36.90 | B | O |
| ATOM | 865 | N | TYR | B | 218 | 44.689 | 38.267 | 69.328 | 1.00 | 37.81 | B | N |
| ATOM | 866 | CA | TYR | B | 218 | 45.205 | 37.077 | 69.981 | 1.00 | 39.95 | B | C |
| ATOM | 867 | CB | TYR | B | 218 | 45.279 | 35.914 | 68.999 | 1.00 | 36.35 | B | C |
| ATOM | 868 | CG | TYR | B | 218 | 43.918 | 35.491 | 68.519 | 1.00 | 34.75 | B | C |
| ATOM | 869 | CD1 | TYR | B | 218 | 43.209 | 34.492 | 69.175 | 1.00 | 34.09 | B | C |
| ATOM | 870 | CE1 | TYR | B | 218 | 41.916 | 34.151 | 68.787 | 1.00 | 34.21 | B | C |
| ATOM | 871 | CD2 | TYR | B | 218 | 43.306 | 36.140 | 67.451 | 1.00 | 34.15 | B | C |
| ATOM | 872 | CE2 | TYR | B | 218 | 42.017 | 35.810 | 67.051 | 1.00 | 35.22 | B | C |
| ATOM | 873 | CZ | TYR | B | 218 | 41.326 | 34.817 | 67.725 | 1.00 | 35.77 | B | C |
| ATOM | 874 | OH | TYR | B | 218 | 40.042 | 34.498 | 67.342 | 1.00 | 37.25 | B | O |
| ATOM | 875 | C | TYR | B | 218 | 46.576 | 37.418 | 70.506 | 1.00 | 44.14 | B | C |
| ATOM | 876 | O | TYR | B | 218 | 47.401 | 37.998 | 69.794 | 1.00 | 43.06 | B | O |
| ATOM | 877 | N | ALA | B | 219 | 46.800 | 37.081 | 71.771 | 1.00 | 50.08 | B | N |
| ATOM | 878 | CA | ALA | B | 219 | 48.069 | 37.360 | 72.418 | 1.00 | 53.91 | B | C |
| ATOM | 879 | CB | ALA | B | 219 | 48.130 | 36.680 | 73.782 | 1.00 | 55.44 | B | C |
| ATOM | 880 | C | ALA | B | 219 | 49.191 | 36.860 | 71.535 | 1.00 | 56.45 | B | C |
| ATOM | 881 | O | ALA | B | 219 | 49.081 | 35.791 | 70.939 | 1.00 | 54.02 | B | O |
| ATOM | 882 | N | ASN | B | 220 | 50.246 | 37.667 | 71.450 | 1.00 | 60.06 | B | N |
| ATOM | 883 | CA | ASN | B | 220 | 51.450 | 37.382 | 70.671 | 1.00 | 63.32 | B | C |
| ATOM | 884 | CB | ASN | B | 220 | 52.665 | 37.939 | 71.425 | 1.00 | 64.92 | B | C |
| ATOM | 885 | CG | ASN | B | 220 | 52.275 | 38.630 | 72.734 | 1.00 | 66.75 | B | C |
| ATOM | 886 | OD1 | ASN | B | 220 | 52.527 | 39.821 | 72.922 | 1.00 | 68.16 | B | O |
| ATOM | 887 | ND2 | ASN | B | 220 | 51.654 | 37.882 | 73.639 | 1.00 | 67.90 | B | N |
| ATOM | 888 | C | ASN | B | 220 | 51.618 | 35.882 | 70.421 | 1.00 | 64.28 | B | C |
| ATOM | 889 | O | ASN | B | 220 | 52.555 | 35.247 | 70.916 | 1.00 | 65.08 | B | O |
| ATOM | 890 | N | GLU | B | 221 | 50.708 | 35.325 | 69.632 | 1.00 | 64.48 | B | N |
| ATOM | 891 | CA | GLU | B | 221 | 50.727 | 33.905 | 69.343 | 1.00 | 65.20 | B | C |
| ATOM | 892 | CB | GLU | B | 221 | 50.154 | 33.122 | 70.523 | 1.00 | 66.28 | B | C |
| ATOM | 893 | CG | GLU | B | 221 | 51.164 | 32.352 | 71.329 | 1.00 | 69.50 | B | C |
| ATOM | 894 | CD | GLU | B | 221 | 50.551 | 31.710 | 72.566 | 1.00 | 72.91 | B | C |
| ATOM | 895 | OE1 | GLU | B | 221 | 49.553 | 30.970 | 72.421 | 1.00 | 74.57 | B | O |
| ATOM | 896 | OE2 | GLU | B | 221 | 51.062 | 31.944 | 73.684 | 1.00 | 74.76 | B | O |
| ATOM | 897 | C | GLU | B | 221 | 49.880 | 33.617 | 68.127 | 1.00 | 64.34 | B | C |
| ATOM | 898 | O | GLU | B | 221 | 48.660 | 33.798 | 68.156 | 1.00 | 63.32 | B | O |
| ATOM | 899 | N | ALA | B | 222 | 50.525 | 33.167 | 67.056 | 1.00 | 63.85 | B | N |
| ATOM | 900 | CA | ALA | B | 222 | 49.797 | 32.810 | 65.852 | 1.00 | 62.78 | B | C |
| ATOM | 901 | CB | ALA | B | 222 | 50.766 | 32.399 | 64.748 | 1.00 | 62.07 | B | C |
| ATOM | 902 | C | ALA | B | 222 | 48.931 | 31.627 | 66.295 | 1.00 | 62.61 | B | C |
| ATOM | 903 | O | ALA | B | 222 | 48.206 | 31.027 | 65.503 | 1.00 | 61.19 | B | O |
| ATOM | 904 | N | ALA | B | 223 | 49.030 | 31.312 | 67.586 | 1.00 | 63.31 | B | N |
| ATOM | 905 | CA | ALA | B | 223 | 48.273 | 30.241 | 68.218 | 1.00 | 64.52 | B | C |
| ATOM | 906 | CB | ALA | B | 223 | 48.811 | 29.985 | 69.614 | 1.00 | 63.61 | B | C |
| ATOM | 907 | C | ALA | B | 223 | 46.802 | 30.652 | 68.288 | 1.00 | 65.87 | B | C |
| ATOM | 908 | O | ALA | B | 223 | 46.089 | 30.337 | 69.246 | 1.00 | 65.69 | B | O |
| ATOM | 909 | N | ALA | B | 224 | 46.368 | 31.386 | 67.268 | 1.00 | 66.60 | B | N |
| ATOM | 910 | CA | ALA | B | 224 | 44.990 | 31.828 | 67.164 | 1.00 | 66.68 | B | C |
| ATOM | 911 | CB | ALA | B | 224 | 44.883 | 32.966 | 66.166 | 1.00 | 65.24 | B | C |
| ATOM | 912 | C | ALA | B | 224 | 44.215 | 30.615 | 66.667 | 1.00 | 67.52 | B | C |
| ATOM | 913 | O | ALA | B | 224 | 42.986 | 30.650 | 66.555 | 1.00 | 67.60 | B | O |
| ATOM | 914 | N | GLY | B | 225 | 44.960 | 29.546 | 66.364 | 1.00 | 68.19 | B | N |
| ATOM | 915 | CA | GLY | B | 225 | 44.364 | 28.305 | 65.895 | 1.00 | 67.94 | B | C |
| ATOM | 916 | C | GLY | B | 225 | 43.334 | 27.868 | 66.913 | 1.00 | 67.89 | B | C |
| ATOM | 917 | O | GLY | B | 225 | 42.253 | 27.383 | 66.573 | 1.00 | 68.03 | B | O |
| ATOM | 918 | N | LYS | B | 226 | 43.692 | 28.031 | 68.180 | 1.00 | 67.33 | B | N |
| ATOM | 919 | CA | LYS | B | 226 | 42.785 | 27.717 | 69.265 | 1.00 | 66.68 | B | C |
| ATOM | 920 | CB | LYS | B | 226 | 43.550 | 27.185 | 70.476 | 1.00 | 66.85 | B | C |
| ATOM | 921 | CG | LYS | B | 226 | 42.765 | 26.174 | 71.291 | 1.00 | 68.82 | B | C |
| ATOM | 922 | CD | LYS | B | 226 | 42.758 | 24.807 | 70.617 | 1.00 | 70.94 | B | C |
| ATOM | 923 | CE | LYS | B | 226 | 42.678 | 23.678 | 71.639 | 1.00 | 71.46 | B | C |
| ATOM | 924 | NZ | LYS | B | 226 | 44.029 | 23.167 | 72.028 | 1.00 | 72.86 | B | N |
| ATOM | 925 | C | LYS | B | 226 | 42.165 | 29.071 | 69.583 | 1.00 | 66.32 | B | C |
| ATOM | 926 | O | LYS | B | 226 | 42.838 | 29.962 | 70.109 | 1.00 | 67.30 | B | O |
| ATOM | 927 | N | ASP | B | 227 | 40.897 | 29.240 | 69.223 | 1.00 | 63.43 | B | N |
| ATOM | 928 | CA | ASP | B | 227 | 40.200 | 30.494 | 69.467 | 1.00 | 60.57 | B | C |
| ATOM | 929 | CB | ASP | B | 227 | 38.717 | 30.342 | 69.138 | 1.00 | 61.14 | B | C |
| ATOM | 930 | CG | ASP | B | 227 | 38.337 | 31.041 | 67.851 | 1.00 | 62.69 | B | C |
| ATOM | 931 | OD1 | ASP | B | 227 | 37.990 | 30.338 | 66.874 | 1.00 | 61.60 | B | O |
| ATOM | 932 | OD2 | ASP | B | 227 | 38.392 | 32.294 | 67.822 | 1.00 | 61.30 | B | O |
| ATOM | 933 | C | ASP | B | 227 | 40.367 | 30.929 | 70.914 | 1.00 | 58.09 | B | C |
| ATOM | 934 | O | ASP | B | 227 | 39.518 | 30.652 | 71.761 | 1.00 | 58.98 | B | O |
| ATOM | 935 | N | GLU | B | 228 | 41.473 | 31.610 | 71.190 | 1.00 | 54.95 | B | N |
| ATOM | 936 | CA | GLU | B | 228 | 41.768 | 32.085 | 72.533 | 1.00 | 52.63 | B | C |
| ATOM | 937 | CB | GLU | B | 228 | 42.812 | 31.182 | 73.195 | 1.00 | 53.66 | B | C |
| ATOM | 938 | CG | GLU | B | 228 | 42.226 | 29.901 | 73.779 | 1.00 | 56.69 | B | C |
| ATOM | 939 | CD | GLU | B | 228 | 43.234 | 28.762 | 73.862 | 1.00 | 58.56 | B | C |
| ATOM | 940 | OE1 | GLU | B | 228 | 44.454 | 29.040 | 73.953 | 1.00 | 58.45 | B | O |
| ATOM | 941 | OE2 | GLU | B | 228 | 42.800 | 27.587 | 73.839 | 1.00 | 58.32 | B | O |
| ATOM | 942 | C | GLU | B | 228 | 42.284 | 33.511 | 72.444 | 1.00 | 49.13 | B | C |
| ATOM | 943 | O | GLU | B | 228 | 43.455 | 33.779 | 72.724 | 1.00 | 49.40 | B | O |
| ATOM | 944 | N | PRO | B | 229 | 41.409 | 34.449 | 72.049 | 1.00 | 46.36 | B | N |
| ATOM | 945 | CD | PRO | B | 229 | 39.992 | 34.222 | 71.711 | 1.00 | 45.34 | B | C |
| ATOM | 946 | CA | PRO | B | 229 | 41.777 | 35.861 | 71.917 | 1.00 | 44.50 | B | C |
| ATOM | 947 | CB | PRO | B | 229 | 40.508 | 36.513 | 71.374 | 1.00 | 44.48 | B | C |
| ATOM | 948 | CG | PRO | B | 229 | 39.407 | 35.594 | 71.789 | 1.00 | 43.80 | B | C |
| ATOM | 949 | C | PRO | B | 229 | 42.198 | 36.467 | 73.241 | 1.00 | 43.57 | B | C |
| ATOM | 950 | O | PRO | B | 229 | 41.914 | 35.913 | 74.295 | 1.00 | 42.02 | B | O |
| ATOM | 951 | N | LYS | B | 230 | 42.886 | 37.599 | 73.179 | 1.00 | 44.06 | B | N |
| ATOM | 952 | CA | LYS | B | 230 | 43.315 | 38.287 | 74.384 | 1.00 | 44.47 | B | C |
| ATOM | 953 | CB | LYS | B | 230 | 44.057 | 39.579 | 74.030 | 1.00 | 45.82 | B | C |
| ATOM | 954 | CG | LYS | B | 230 | 45.572 | 39.469 | 74.053 | 1.00 | 46.83 | B | C |
| ATOM | 955 | CD | LYS | B | 230 | 46.087 | 39.352 | 75.474 | 1.00 | 49.28 | B | C |
| ATOM | 956 | CE | LYS | B | 230 | 47.367 | 40.141 | 75.663 | 1.00 | 50.07 | B | C |
| ATOM | 957 | NZ | LYS | B | 230 | 48.565 | 39.292 | 75.412 | 1.00 | 50.85 | B | N |
| ATOM | 958 | C | LYS | B | 230 | 42.037 | 38.629 | 75.139 | 1.00 | 45.81 | B | C |
| ATOM | 959 | O | LYS | B | 230 | 41.059 | 39.083 | 74.537 | 1.00 | 46.01 | B | O |
| ATOM | 960 | N | PRO | B | 231 | 42.019 | 38.399 | 76.463 | 1.00 | 45.78 | B | N |
| ATOM | 961 | CD | PRO | B | 231 | 43.093 | 37.835 | 77.303 | 1.00 | 45.97 | B | C |
| ATOM | 962 | CA | PRO | B | 231 | 40.821 | 38.710 | 77.246 | 1.00 | 45.48 | B | C |
| ATOM | 963 | CB | PRO | B | 231 | 41.310 | 38.630 | 78.690 | 1.00 | 45.95 | B | C |
| ATOM | 964 | CG | PRO | B | 231 | 42.415 | 37.620 | 78.635 | 1.00 | 46.16 | B | C |
| ATOM | 965 | C | PRO | B | 231 | 40.268 | 40.087 | 76.890 | 1.00 | 44.57 | B | C |
| ATOM | 966 | O | PRO | B | 231 | 40.973 | 41.095 | 76.973 | 1.00 | 44.06 | B | O |
| ATOM | 967 | N | LEU | B | 232 | 39.005 | 40.110 | 76.477 | 1.00 | 44.42 | B | N |
| ATOM | 968 | CA | LEU | B | 232 | 38.330 | 41.343 | 76.093 | 1.00 | 44.07 | B | C |
| ATOM | 969 | CB | LEU | B | 232 | 38.940 | 41.895 | 74.803 | 1.00 | 44.35 | B | C |
| ATOM | 970 | CG | LEU | B | 232 | 38.779 | 43.389 | 74.524 | 1.00 | 44.23 | B | C |
| ATOM | 971 | CD1 | LEU | B | 232 | 40.031 | 43.919 | 73.827 | 1.00 | 44.79 | B | C |
| ATOM | 972 | CD2 | LEU | B | 232 | 37.545 | 43.611 | 73.661 | 1.00 | 44.97 | B | C |
| ATOM | 973 | C | LEU | B | 232 | 36.847 | 41.069 | 75.879 | 1.00 | 43.47 | B | C |
| ATOM | 974 | O | LEU | B | 232 | 36.438 | 39.927 | 75.664 | 1.00 | 42.07 | B | O |
| ATOM | 975 | N | LEU | B | 233 | 36.039 | 42.119 | 75.955 | 1.00 | 44.04 | B | N |
| ATOM | 976 | CA | LEU | B | 233 | 34.602 | 41.981 | 75.744 | 1.00 | 43.09 | B | C |
| ATOM | 977 | CB | LEU | B | 233 | 33.830 | 42.954 | 76.647 | 1.00 | 46.53 | B | C |
| ATOM | 978 | CG | LEU | B | 233 | 34.064 | 44.454 | 76.414 | 1.00 | 49.33 | B | C |
| ATOM | 979 | CD1 | LEU | B | 233 | 32.943 | 45.258 | 77.074 | 1.00 | 48.66 | B | C |
| ATOM | 980 | CD2 | LEU | B | 233 | 35.437 | 44.856 | 76.963 | 1.00 | 48.84 | B | C |
| ATOM | 981 | C | LEU | B | 233 | 34.317 | 42.276 | 74.271 | 1.00 | 40.33 | B | C |
| ATOM | 982 | O | LEU | B | 233 | 34.399 | 43.424 | 73.824 | 1.00 | 39.37 | B | O |
| ATOM | 983 | N | TYR | B | 234 | 34.015 | 41.221 | 73.520 | 1.00 | 37.41 | B | N |
| ATOM | 984 | CA | TYR | B | 234 | 33.725 | 41.339 | 72.096 | 1.00 | 34.56 | B | C |
| ATOM | 985 | CB | TYR | B | 234 | 34.309 | 40.134 | 71.338 | 1.00 | 33.43 | B | C |
| ATOM | 986 | CG | TYR | B | 234 | 35.824 | 40.082 | 71.337 | 1.00 | 32.69 | B | C |
| ATOM | 987 | CD1 | TYR | B | 234 | 36.517 | 39.459 | 72.375 | 1.00 | 32.98 | B | C |
| ATOM | 988 | CE1 | TYR | B | 234 | 37.916 | 39.424 | 72.396 | 1.00 | 32.99 | B | C |
| ATOM | 989 | CD2 | TYR | B | 234 | 36.570 | 40.674 | 70.311 | 1.00 | 31.95 | B | C |
| ATOM | 990 | CE2 | TYR | B | 234 | 37.971 | 40.645 | 70.322 | 1.00 | 31.94 | B | C |
| ATOM | 991 | CZ | TYR | B | 234 | 38.635 | 40.019 | 71.368 | 1.00 | 32.84 | B | C |
| ATOM | 992 | OH | TYR | B | 234 | 40.012 | 39.987 | 71.398 | 1.00 | 34.17 | B | O |
| ATOM | 993 | C | TYR | B | 234 | 32.214 | 41.412 | 71.897 | 1.00 | 33.12 | B | C |
| ATOM | 994 | O | TYR | B | 234 | 31.445 | 41.056 | 72.793 | 1.00 | 32.15 | B | O |
| ATOM | 995 | N | PRO | B | 235 | 31.766 | 41.877 | 70.718 | 1.00 | 31.02 | B | N |
| ATOM | 996 | CD | PRO | B | 235 | 32.584 | 42.317 | 69.577 | 1.00 | 30.54 | B | C |
| ATOM | 997 | CA | PRO | B | 235 | 30.331 | 41.986 | 70.435 | 1.00 | 29.49 | B | C |
| ATOM | 998 | CB | PRO | B | 235 | 30.279 | 42.576 | 69.026 | 1.00 | 30.76 | B | C |
| ATOM | 999 | CG | PRO | B | 235 | 31.636 | 43.155 | 68.792 | 1.00 | 29.97 | B | C |
| ATOM | 1000 | C | PRO | B | 235 | 29.617 | 40.646 | 70.501 | 1.00 | 27.19 | B | C |
| ATOM | 1001 | O | PRO | B | 235 | 30.199 | 39.615 | 70.203 | 1.00 | 27.88 | B | O |
| ATOM | 1002 | N | ASN | B | 236 | 28.349 | 40.673 | 70.884 | 1.00 | 26.49 | B | N |
| ATOM | 1003 | CA | ASN | B | 236 | 27.544 | 39.464 | 70.983 | 1.00 | 26.86 | B | C |
| ATOM | 1004 | CB | ASN | B | 236 | 27.060 | 39.282 | 72.419 | 1.00 | 27.30 | B | C |
| ATOM | 1005 | CG | ASN | B | 236 | 26.349 | 37.968 | 72.632 | 1.00 | 28.72 | B | C |
| ATOM | 1006 | OD1 | ASN | B | 236 | 25.542 | 37.539 | 71.803 | 1.00 | 30.48 | B | O |
| ATOM | 1007 | ND2 | ASN | B | 236 | 26.641 | 37.316 | 73.751 | 1.00 | 29.98 | B | N |
| ATOM | 1008 | C | ASN | B | 236 | 26.351 | 39.616 | 70.043 | 1.00 | 27.74 | B | C |
| ATOM | 1009 | O | ASN | B | 236 | 25.336 | 40.218 | 70.407 | 1.00 | 27.96 | B | O |
| ATOM | 1010 | N | MET | B | 237 | 26.468 | 39.061 | 68.840 | 1.00 | 26.94 | B | N |
| ATOM | 1011 | CA | MET | B | 237 | 25.407 | 39.181 | 67.853 | 1.00 | 27.71 | B | C |
| ATOM | 1012 | CB | MET | B | 237 | 25.820 | 38.547 | 66.534 | 1.00 | 30.70 | B | C |
| ATOM | 1013 | CG | MET | B | 237 | 24.916 | 38.980 | 65.395 | 1.00 | 33.93 | B | C |
| ATOM | 1014 | SD | MET | B | 237 | 25.529 | 38.479 | 63.804 | 1.00 | 40.48 | B | S |
| ATOM | 1015 | CE | MET | B | 237 | 24.454 | 37.062 | 63.472 | 1.00 | 38.91 | B | C |
| ATOM | 1016 | C | MET | B | 237 | 24.042 | 38.643 | 68.237 | 1.00 | 27.40 | B | C |
| ATOM | 1017 | O | MET | B | 237 | 23.027 | 39.239 | 67.887 | 1.00 | 27.65 | B | O |
| ATOM | 1018 | N | GLU | B | 238 | 23.999 | 37.520 | 68.939 | 1.00 | 27.87 | B | N |
| ATOM | 1019 | CA | GLU | B | 238 | 22.716 | 36.959 | 69.336 | 1.00 | 29.78 | B | C |
| ATOM | 1020 | CB | GLU | B | 238 | 22.912 | 35.626 | 70.060 | 1.00 | 34.45 | B | C |
| ATOM | 1021 | CG | GLU | B | 238 | 21.701 | 34.710 | 69.958 | 1.00 | 43.24 | B | C |
| ATOM | 1022 | CD | GLU | B | 238 | 21.810 | 33.474 | 70.840 | 1.00 | 48.24 | B | C |
| ATOM | 1023 | OE1 | GLU | B | 238 | 20.796 | 33.112 | 71.485 | 1.00 | 49.98 | B | O |
| ATOM | 1024 | OE2 | GLU | B | 238 | 22.906 | 32.866 | 70.884 | 1.00 | 50.61 | B | O |
| ATOM | 1025 | C | GLU | B | 238 | 21.987 | 37.938 | 70.247 | 1.00 | 27.75 | B | C |
| ATOM | 1026 | O | GLU | B | 238 | 20.769 | 38.120 | 70.149 | 1.00 | 24.73 | B | O |
| ATOM | 1027 | N | GLU | B | 239 | 22.747 | 38.567 | 71.133 | 1.00 | 25.42 | B | N |
| ATOM | 1028 | CA | GLU | B | 239 | 22.193 | 39.534 | 72.062 | 1.00 | 25.49 | B | C |
| ATOM | 1029 | CB | GLU | B | 239 | 23.265 | 39.917 | 73.086 | 1.00 | 27.17 | B | C |
| ATOM | 1030 | CG | GLU | B | 239 | 22.831 | 40.924 | 74.142 | 1.00 | 29.65 | B | C |
| ATOM | 1031 | CD | GLU | B | 239 | 23.974 | 41.302 | 75.065 | 1.00 | 29.67 | B | C |
| ATOM | 1032 | OE1 | GLU | B | 239 | 23.881 | 42.342 | 75.747 | 1.00 | 31.26 | B | O |
| ATOM | 1033 | OE2 | GLU | B | 239 | 24.971 | 40.554 | 75.105 | 1.00 | 31.42 | B | O |
| ATOM | 1034 | C | GLU | B | 239 | 21.731 | 40.763 | 71.285 | 1.00 | 23.51 | B | C |
| ATOM | 1035 | O | GLU | B | 239 | 20.653 | 41.302 | 71.535 | 1.00 | 22.40 | B | O |
| ATOM | 1036 | N | PHE | B | 240 | 22.556 | 41.200 | 70.337 | 1.00 | 22.94 | B | N |
| ATOM | 1037 | CA | PHE | B | 240 | 22.229 | 42.365 | 69.523 | 1.00 | 22.43 | B | C |
| ATOM | 1038 | CB | PHE | B | 240 | 23.343 | 42.654 | 68.517 | 1.00 | 21.57 | B | C |
| ATOM | 1039 | CG | PHE | B | 240 | 23.090 | 43.868 | 67.676 | 1.00 | 22.29 | B | C |
| ATOM | 1040 | CD1 | PHE | B | 240 | 22.199 | 43.822 | 66.614 | 1.00 | 22.43 | B | C |
| ATOM | 1041 | CD2 | PHE | B | 240 | 23.731 | 45.067 | 67.956 | 1.00 | 24.08 | B | C |
| ATOM | 1042 | CE1 | PHE | B | 240 | 21.946 | 44.955 | 65.841 | 1.00 | 22.53 | B | C |
| ATOM | 1043 | CE2 | PHE | B | 240 | 23.485 | 46.207 | 67.189 | 1.00 | 23.84 | B | C |
| ATOM | 1044 | CZ | PHE | B | 240 | 22.589 | 46.147 | 66.129 | 1.00 | 21.86 | B | C |
| ATOM | 1045 | C | PHE | B | 240 | 20.927 | 42.150 | 68.772 | 1.00 | 21.60 | B | C |
| ATOM | 1046 | O | PHE | B | 240 | 20.060 | 43.021 | 68.747 | 1.00 | 20.48 | B | O |
| ATOM | 1047 | N | LEU | B | 241 | 20.799 | 40.981 | 68.158 | 1.00 | 22.14 | B | N |
| ATOM | 1048 | CA | LEU | B | 241 | 19.601 | 40.648 | 67.403 | 1.00 | 22.98 | B | C |
| ATOM | 1049 | CB | LEU | B | 241 | 19.817 | 39.338 | 66.642 | 1.00 | 22.46 | B | C |
| ATOM | 1050 | CG | LEU | B | 241 | 20.833 | 39.430 | 65.493 | 1.00 | 24.93 | B | C |
| ATOM | 1051 | CD1 | LEU | B | 241 | 21.155 | 38.041 | 64.951 | 1.00 | 23.99 | B | C |
| ATOM | 1052 | CD2 | LEU | B | 241 | 20.270 | 40.314 | 64.391 | 1.00 | 24.24 | B | C |
| ATOM | 1053 | C | LEU | B | 241 | 18.365 | 40.545 | 68.300 | 1.00 | 24.32 | B | C |
| ATOM | 1054 | O | LEU | B | 241 | 17.248 | 40.839 | 67.869 | 1.00 | 24.13 | B | O |
| ATOM | 1055 | N | ASP | B | 242 | 18.557 | 40.131 | 69.550 | 1.00 | 25.33 | B | N |
| ATOM | 1056 | CA | ASP | B | 242 | 17.428 | 40.017 | 70.471 | 1.00 | 26.80 | B | C |
| ATOM | 1057 | CB | ASP | B | 242 | 17.840 | 39.286 | 71.754 | 1.00 | 31.97 | B | C |
| ATOM | 1058 | CG | ASP | B | 242 | 17.997 | 37.788 | 71.550 | 1.00 | 38.73 | B | C |
| ATOM | 1059 | OD1 | ASP | B | 242 | 17.485 | 37.257 | 70.534 | 1.00 | 42.52 | B | O |
| ATOM | 1060 | OD2 | ASP | B | 242 | 18.638 | 37.139 | 72.409 | 1.00 | 42.65 | B | O |
| ATOM | 1061 | C | ASP | B | 242 | 16.910 | 41.402 | 70.828 | 1.00 | 24.89 | B | C |
| ATOM | 1062 | O | ASP | B | 242 | 15.705 | 41.639 | 70.844 | 1.00 | 23.48 | B | O |
| ATOM | 1063 | N | ASP | B | 243 | 17.838 | 42.310 | 71.113 | 1.00 | 23.63 | B | N |
| ATOM | 1064 | CA | ASP | B | 243 | 17.495 | 43.678 | 71.475 | 1.00 | 22.83 | B | C |
| ATOM | 1065 | CB | ASP | B | 243 | 18.744 | 44.417 | 71.963 | 1.00 | 22.53 | B | C |
| ATOM | 1066 | CG | ASP | B | 243 | 19.214 | 43.926 | 73.321 | 1.00 | 22.59 | B | C |
| ATOM | 1067 | OD1 | ASP | B | 243 | 18.390 | 43.339 | 74.048 | 1.00 | 21.44 | B | O |
| ATOM | 1068 | OD2 | ASP | B | 243 | 20.398 | 44.122 | 73.664 | 1.00 | 22.39 | B | O |
| ATOM | 1069 | C | ASP | B | 243 | 16.880 | 44.415 | 70.296 | 1.00 | 22.51 | B | C |
| ATOM | 1070 | O | ASP | B | 243 | 15.953 | 45.206 | 70.468 | 1.00 | 22.08 | B | O |
| ATOM | 1071 | N | MET | B | 244 | 17.402 | 44.144 | 69.102 | 1.00 | 22.14 | B | N |
| ATOM | 1072 | CA | MET | B | 244 | 16.914 | 44.766 | 67.875 | 1.00 | 20.87 | B | C |
| ATOM | 1073 | CB | MET | B | 244 | 17.810 | 44.367 | 66.706 | 1.00 | 19.60 | B | C |
| ATOM | 1074 | CG | MET | B | 244 | 17.384 | 44.941 | 65.375 | 1.00 | 20.21 | B | C |
| ATOM | 1075 | SD | MET | B | 244 | 18.199 | 44.103 | 64.004 | 1.00 | 24.14 | B | S |
| ATOM | 1076 | CE | MET | B | 244 | 17.281 | 42.563 | 63.937 | 1.00 | 21.33 | B | C |
| ATOM | 1077 | C | MET | B | 244 | 15.480 | 44.336 | 67.589 | 1.00 | 20.68 | B | C |
| ATOM | 1078 | O | MET | B | 244 | 14.629 | 45.149 | 67.222 | 1.00 | 20.83 | B | O |
| ATOM | 1079 | N | ASN | B | 245 | 15.218 | 43.047 | 67.764 | 1.00 | 20.64 | B | N |
| ATOM | 1080 | CA | ASN | B | 245 | 13.890 | 42.501 | 67.524 | 1.00 | 22.09 | B | C |
| ATOM | 1081 | CB | ASN | B | 245 | 13.934 | 40.979 | 67.622 | 1.00 | 21.79 | B | C |
| ATOM | 1082 | CG | ASN | B | 245 | 14.498 | 40.340 | 66.373 | 1.00 | 24.03 | B | C |
| ATOM | 1083 | OD1 | ASN | B | 245 | 14.145 | 40.722 | 65.258 | 1.00 | 24.38 | B | O |
| ATOM | 1084 | ND2 | ASN | B | 245 | 15.382 | 39.367 | 66.552 | 1.00 | 25.22 | B | N |
| ATOM | 1085 | C | ASN | B | 245 | 12.872 | 43.062 | 68.511 | 1.00 | 22.71 | B | C |
| ATOM | 1086 | O | ASN | B | 245 | 11.687 | 43.204 | 68.191 | 1.00 | 23.40 | B | O |
| ATOM | 1087 | N | PHE | B | 246 | 13.339 | 43.379 | 69.716 | 1.00 | 22.39 | B | N |
| ATOM | 1088 | CA | PHE | B | 246 | 12.471 | 43.935 | 70.742 | 1.00 | 20.20 | B | C |
| ATOM | 1089 | CB | PHE | B | 246 | 13.169 | 43.922 | 72.104 | 1.00 | 20.00 | B | C |
| ATOM | 1090 | CG | PHE | B | 246 | 12.679 | 44.988 | 73.038 | 1.00 | 21.63 | B | C |
| ATOM | 1091 | CD1 | PHE | B | 246 | 13.394 | 46.167 | 73.202 | 1.00 | 21.69 | B | C |
| ATOM | 1092 | CD2 | PHE | B | 246 | 11.485 | 44.829 | 73.723 | 1.00 | 23.57 | B | C |
| ATOM | 1093 | CE1 | PHE | B | 246 | 12.928 | 47.168 | 74.030 | 1.00 | 23.22 | B | C |
| ATOM | 1094 | CE2 | PHE | B | 246 | 11.010 | 45.829 | 74.558 | 1.00 | 24.29 | B | C |
| ATOM | 1095 | CZ | PHE | B | 246 | 11.733 | 46.999 | 74.711 | 1.00 | 24.26 | B | C |
| ATOM | 1096 | C | PHE | B | 246 | 12.111 | 45.366 | 70.368 | 1.00 | 18.58 | B | C |
| ATOM | 1097 | O | PHE | B | 246 | 10.952 | 45.764 | 70.459 | 1.00 | 18.79 | B | O |
| ATOM | 1098 | N | LEU | B | 247 | 13.112 | 46.139 | 69.954 | 1.00 | 17.51 | B | N |
| ATOM | 1099 | CA | LEU | B | 247 | 12.884 | 47.525 | 69.565 | 1.00 | 18.19 | B | C |
| ATOM | 1100 | CB | LEU | B | 247 | 14.219 | 48.235 | 69.330 | 1.00 | 16.40 | B | C |
| ATOM | 1101 | CG | LEU | B | 247 | 15.020 | 48.531 | 70.604 | 1.00 | 15.74 | B | C |
| ATOM | 1102 | CD1 | LEU | B | 247 | 16.402 | 49.066 | 70.245 | 1.00 | 12.05 | B | C |
| ATOM | 1103 | CD2 | LEU | B | 247 | 14.261 | 49.541 | 71.456 | 1.00 | 12.60 | B | C |
| ATOM | 1104 | C | LEU | B | 247 | 12.018 | 47.581 | 68.306 | 1.00 | 19.22 | B | C |
| ATOM | 1105 | O | LEU | B | 247 | 11.178 | 48.465 | 68.160 | 1.00 | 19.67 | B | O |
| ATOM | 1106 | N | LEU | B | 248 | 12.216 | 46.625 | 67.402 | 1.00 | 21.15 | B | N |
| ATOM | 1107 | CA | LEU | B | 248 | 11.425 | 46.583 | 66.180 | 1.00 | 21.76 | B | C |
| ATOM | 1108 | CB | LEU | B | 248 | 11.867 | 45.409 | 65.299 | 1.00 | 22.42 | B | C |
| ATOM | 1109 | CG | LEU | B | 248 | 12.428 | 45.662 | 63.890 | 1.00 | 24.19 | B | C |
| ATOM | 1110 | CD1 | LEU | B | 248 | 12.934 | 47.091 | 63.733 | 1.00 | 25.84 | B | C |
| ATOM | 1111 | CD2 | LEU | B | 248 | 13.553 | 44.674 | 63.631 | 1.00 | 22.53 | B | C |
| ATOM | 1112 | C | LEU | B | 248 | 9.959 | 46.429 | 66.573 | 1.00 | 22.08 | B | C |
| ATOM | 1113 | O | LEU | B | 248 | 9.083 | 47.088 | 66.015 | 1.00 | 24.50 | B | O |
| ATOM | 1114 | N | ALA | B | 249 | 9.694 | 45.569 | 67.549 | 1.00 | 21.15 | B | N |
| ATOM | 1115 | CA | ALA | B | 249 | 8.328 | 45.345 | 68.006 | 1.00 | 22.38 | B | C |
| ATOM | 1116 | CB | ALA | B | 249 | 8.279 | 44.122 | 68.923 | 1.00 | 22.67 | B | C |
| ATOM | 1117 | C | ALA | B | 249 | 7.781 | 46.572 | 68.740 | 1.00 | 23.39 | B | C |
| ATOM | 1118 | O | ALA | B | 249 | 6.645 | 47.005 | 68.517 | 1.00 | 23.91 | B | O |
| ATOM | 1119 | N | LEU | B | 250 | 8.608 | 47.132 | 69.614 | 1.00 | 24.06 | B | N |
| ATOM | 1120 | CA | LEU | B | 250 | 8.227 | 48.293 | 70.399 | 1.00 | 22.02 | B | C |
| ATOM | 1121 | CB | LEU | B | 250 | 9.400 | 48.725 | 71.280 | 1.00 | 20.82 | B | C |
| ATOM | 1122 | CG | LEU | B | 250 | 9.115 | 49.845 | 72.279 | 1.00 | 18.57 | B | C |
| ATOM | 1123 | CD1 | LEU | B | 250 | 8.305 | 49.284 | 73.420 | 1.00 | 16.57 | B | C |
| ATOM | 1124 | CD2 | LEU | B | 250 | 10.413 | 50.452 | 72.779 | 1.00 | 17.76 | B | C |
| ATOM | 1125 | C | LEU | B | 250 | 7.750 | 49.474 | 69.564 | 1.00 | 24.02 | B | C |
| ATOM | 1126 | O | LEU | B | 250 | 6.656 | 49.984 | 69.799 | 1.00 | 24.26 | B | O |
| ATOM | 1127 | N | ILE | B | 251 | 8.555 | 49.914 | 68.594 | 1.00 | 23.37 | B | N |
| ATOM | 1128 | CA | ILE | B | 251 | 8.171 | 51.064 | 67.773 | 1.00 | 24.18 | B | C |
| ATOM | 1129 | CB | ILE | B | 251 | 9.305 | 51.501 | 66.812 | 1.00 | 23.82 | B | C |
| ATOM | 1130 | CG2 | ILE | B | 251 | 10.596 | 51.676 | 67.580 | 1.00 | 21.78 | B | C |
| ATOM | 1131 | CG1 | ILE | B | 251 | 9.479 | 50.476 | 65.694 | 1.00 | 23.76 | B | C |
| ATOM | 1132 | CD1 | ILE | B | 251 | 10.601 | 50.824 | 64.740 | 1.00 | 24.98 | B | C |
| ATOM | 1133 | C | ILE | B | 251 | 6.907 | 50.837 | 66.953 | 1.00 | 24.08 | B | C |
| ATOM | 1134 | O | ILE | B | 251 | 6.318 | 51.789 | 66.435 | 1.00 | 25.12 | B | O |
| ATOM | 1135 | N | ALA | B | 252 | 6.484 | 49.581 | 66.850 | 1.00 | 23.78 | B | N |
| ATOM | 1136 | CA | ALA | B | 252 | 5.294 | 49.241 | 66.092 | 1.00 | 24.71 | B | C |
| ATOM | 1137 | CB | ALA | B | 252 | 5.564 | 48.021 | 65.226 | 1.00 | 24.30 | B | C |
| ATOM | 1138 | C | ALA | B | 252 | 4.095 | 48.988 | 66.996 | 1.00 | 26.09 | B | C |
| ATOM | 1139 | O | ALA | B | 252 | 2.978 | 48.799 | 66.513 | 1.00 | 27.26 | B | O |
| ATOM | 1140 | N | GLN | B | 253 | 4.330 | 48.991 | 68.307 | 1.00 | 27.10 | B | N |
| ATOM | 1141 | CA | GLN | B | 253 | 3.273 | 48.766 | 69.300 | 1.00 | 28.60 | B | C |
| ATOM | 1142 | CB | GLN | B | 253 | 3.889 | 48.571 | 70.680 | 1.00 | 31.94 | B | C |
| ATOM | 1143 | CG | GLN | B | 253 | 3.430 | 47.319 | 71.393 | 1.00 | 34.77 | B | C |
| ATOM | 1144 | CD | GLN | B | 253 | 4.424 | 46.879 | 72.442 | 1.00 | 36.71 | B | C |
| ATOM | 1145 | OE1 | GLN | B | 253 | 5.089 | 45.854 | 72.292 | 1.00 | 39.94 | B | O |
| ATOM | 1146 | NE2 | GLN | B | 253 | 4.538 | 47.655 | 73.512 | 1.00 | 38.26 | B | N |
| ATOM | 1147 | C | GLN | B | 253 | 2.267 | 49.913 | 69.368 | 1.00 | 27.10 | B | C |
| ATOM | 1148 | O | GLN | B | 253 | 2.639 | 51.067 | 69.584 | 1.00 | 25.95 | B | O |
| ATOM | 1149 | N | GLY | B | 254 | 0.991 | 49.574 | 69.209 | 1.00 | 26.81 | B | N |
| ATOM | 1150 | CA | GLY | B | 254 | −0.072 | 50.569 | 69.216 | 1.00 | 25.22 | B | C |
| ATOM | 1151 | C | GLY | B | 254 | −0.093 | 51.509 | 70.399 | 1.00 | 24.02 | B | C |
| ATOM | 1152 | O | GLY | B | 254 | −0.010 | 52.721 | 70.222 | 1.00 | 25.83 | B | O |
| ATOM | 1153 | N | PRO | B | 255 | −0.227 | 50.982 | 71.624 | 1.00 | 23.48 | B | N |
| ATOM | 1154 | CD | PRO | B | 255 | −0.387 | 49.551 | 71.932 | 1.00 | 23.33 | B | C |
| ATOM | 1155 | CA | PRO | B | 255 | −0.260 | 51.804 | 72.839 | 1.00 | 22.12 | B | C |
| ATOM | 1156 | CB | PRO | B | 255 | −0.429 | 50.782 | 73.958 | 1.00 | 21.81 | B | C |
| ATOM | 1157 | CG | PRO | B | 255 | −1.030 | 49.582 | 73.279 | 1.00 | 23.18 | B | C |
| ATOM | 1158 | C | PRO | B | 255 | 0.986 | 52.662 | 73.033 | 1.00 | 21.55 | B | C |
| ATOM | 1159 | O | PRO | B | 255 | 0.894 | 53.787 | 73.512 | 1.00 | 22.17 | B | O |
| ATOM | 1160 | N | VAL | B | 256 | 2.149 | 52.131 | 72.668 | 1.00 | 20.82 | B | N |
| ATOM | 1161 | CA | VAL | B | 256 | 3.393 | 52.879 | 72.806 | 1.00 | 21.02 | B | C |
| ATOM | 1162 | CB | VAL | B | 256 | 4.624 | 51.979 | 72.544 | 1.00 | 20.94 | B | C |
| ATOM | 1163 | CG1 | VAL | B | 256 | 5.910 | 52.751 | 72.828 | 1.00 | 20.04 | B | C |
| ATOM | 1164 | CG2 | VAL | B | 256 | 4.552 | 50.735 | 73.415 | 1.00 | 18.98 | B | C |
| ATOM | 1165 | C | VAL | B | 256 | 3.405 | 54.047 | 71.819 | 1.00 | 21.26 | B | C |
| ATOM | 1166 | O | VAL | B | 256 | 3.883 | 55.139 | 72.130 | 1.00 | 22.37 | B | O |
| ATOM | 1167 | N | LYS | B | 257 | 2.864 | 53.804 | 70.631 | 1.00 | 22.01 | B | N |
| ATOM | 1168 | CA | LYS | B | 257 | 2.798 | 54.819 | 69.584 | 1.00 | 23.53 | B | C |
| ATOM | 1169 | CB | LYS | B | 257 | 2.229 | 54.212 | 68.289 | 1.00 | 24.04 | B | C |
| ATOM | 1170 | CG | LYS | B | 257 | 3.281 | 53.831 | 67.254 | 1.00 | 25.83 | B | C |
| ATOM | 1171 | CD | LYS | B | 257 | 2.906 | 52.560 | 66.514 | 1.00 | 28.08 | B | C |
| ATOM | 1172 | CE | LYS | B | 257 | 2.016 | 52.849 | 65.314 | 1.00 | 30.19 | B | C |
| ATOM | 1173 | NZ | LYS | B | 257 | 0.961 | 51.794 | 65.142 | 1.00 | 34.14 | B | N |
| ATOM | 1174 | C | LYS | B | 257 | 1.913 | 55.972 | 70.042 | 1.00 | 21.25 | B | C |
| ATOM | 1175 | O | LYS | B | 257 | 2.243 | 57.140 | 69.841 | 1.00 | 21.33 | B | O |
| ATOM | 1176 | N | THR | B | 258 | 0.793 | 55.636 | 70.669 | 1.00 | 19.73 | B | N |
| ATOM | 1177 | CA | THR | B | 258 | −0.150 | 56.641 | 71.140 | 1.00 | 20.47 | B | C |
| ATOM | 1178 | CB | THR | B | 258 | −1.460 | 55.987 | 71.583 | 1.00 | 21.66 | B | C |
| ATOM | 1179 | OG1 | TER | B | 258 | −2.088 | 55.391 | 70.446 | 1.00 | 26.56 | B | O |
| ATOM | 1180 | CG2 | TER | B | 258 | −2.405 | 57.022 | 72.184 | 1.00 | 24.36 | B | C |
| ATOM | 1181 | C | THR | B | 258 | 0.403 | 57.463 | 72.297 | 1.00 | 20.10 | B | C |
| ATOM | 1182 | O | THR | B | 258 | 0.328 | 58.691 | 72.292 | 1.00 | 21.30 | B | O |
| ATOM | 1183 | N | TYR | B | 259 | 0.956 | 56.782 | 73.291 | 1.00 | 18.20 | B | N |
| ATOM | 1184 | CA | TYR | B | 259 | 1.517 | 57.467 | 74.439 | 1.00 | 15.69 | B | C |
| ATOM | 1185 | CB | TYR | B | 259 | 2.104 | 56.450 | 75.423 | 1.00 | 16.42 | B | C |
| ATOM | 1186 | CG | TYR | B | 259 | 2.796 | 57.097 | 76.598 | 1.00 | 18.94 | B | C |
| ATOM | 1187 | CD1 | TYR | B | 259 | 4.186 | 57.203 | 76.643 | 1.00 | 18.75 | B | C |
| ATOM | 1188 | CE1 | TYR | B | 259 | 4.822 | 57.836 | 77.707 | 1.00 | 19.68 | B | C |
| ATOM | 1189 | CD2 | TYR | B | 259 | 2.056 | 57.640 | 77.653 | 1.00 | 19.34 | B | C |
| ATOM | 1190 | CE2 | TYR | B | 259 | 2.680 | 58.274 | 78.719 | 1.00 | 19.48 | B | C |
| ATOM | 1191 | CZ | TYR | B | 259 | 4.060 | 58.371 | 78.742 | 1.00 | 20.47 | B | C |
| ATOM | 1192 | OH | TYR | B | 259 | 4.676 | 59.010 | 79.792 | 1.00 | 20.54 | B | O |
| ATOM | 1193 | C | TYR | B | 259 | 2.602 | 58.442 | 73.993 | 1.00 | 14.43 | B | C |
| ATOM | 1194 | O | TYR | B | 259 | 2.544 | 59.632 | 74.301 | 1.00 | 13.39 | B | O |
| ATOM | 1195 | N | THR | B | 260 | 3.591 | 57.935 | 73.261 | 1.00 | 13.65 | B | N |
| ATOM | 1196 | CA | THR | B | 260 | 4.687 | 58.780 | 72.796 | 1.00 | 14.98 | B | C |
| ATOM | 1197 | CB | THR | B | 260 | 5.762 | 57.945 | 72.036 | 1.00 | 16.16 | B | C |
| ATOM | 1198 | OG1 | THR | B | 260 | 5.153 | 57.204 | 70.967 | 1.00 | 13.55 | B | O |
| ATOM | 1199 | CG2 | THR | B | 260 | 6.435 | 56.965 | 72.996 | 1.00 | 13.81 | B | C |
| ATOM | 1200 | C | THR | B | 260 | 4.205 | 59.931 | 71.915 | 1.00 | 12.93 | B | C |
| ATOM | 1201 | O | THR | B | 260 | 4.735 | 61.031 | 71.976 | 1.00 | 14.73 | B | O |
| ATOM | 1202 | N | HIS | B | 261 | 3.188 | 59.677 | 71.104 | 1.00 | 13.89 | B | N |
| ATOM | 1203 | CA | HIS | B | 261 | 2.659 | 60.711 | 70.228 | 1.00 | 16.36 | B | C |
| ATOM | 1204 | CB | HIS | B | 261 | 1.575 | 60.135 | 69.317 | 1.00 | 17.57 | B | C |
| ATOM | 1205 | CG | HIS | B | 261 | 1.038 | 61.125 | 68.330 | 1.00 | 20.36 | B | C |
| ATOM | 1206 | CD2 | HIS | B | 261 | 1.667 | 61.892 | 67.409 | 1.00 | 19.74 | B | C |
| ATOM | 1207 | ND1 | HIS | B | 261 | −0.300 | 61.445 | 68.248 | 1.00 | 19.43 | B | N |
| ATOM | 1208 | CE1 | HIS | B | 261 | −0.473 | 62.367 | 67.321 | 1.00 | 20.12 | B | C |
| ATOM | 1209 | NE2 | HIS | B | 261 | 0.705 | 62.656 | 66.797 | 1.00 | 22.10 | B | N |
| ATOM | 1210 | C | HIS | B | 261 | 2.078 | 61.845 | 71.057 | 1.00 | 15.84 | B | C |
| ATOM | 1211 | O | HIS | B | 261 | 2.322 | 63.022 | 70.787 | 1.00 | 15.81 | B | O |
| ATOM | 1212 | N | ARG | B | 262 | 1.299 | 61.479 | 72.068 | 1.00 | 17.06 | B | N |
| ATOM | 1213 | CA | ARG | B | 262 | 0.682 | 62.455 | 72.961 | 1.00 | 17.70 | B | C |
| ATOM | 1214 | CB | ARG | B | 262 | −0.217 | 61.734 | 73.966 | 1.00 | 20.18 | B | C |
| ATOM | 1215 | CG | ARG | B | 262 | −1.383 | 62.569 | 74.457 | 1.00 | 29.53 | B | C |
| ATOM | 1216 | CD | ARG | B | 262 | −2.172 | 61.848 | 75.541 | 1.00 | 33.85 | B | C |
| ATOM | 1217 | NE | ARG | B | 262 | −2.446 | 60.449 | 75.211 | 1.00 | 38.06 | B | N |
| ATOM | 1218 | CZ | ARG | B | 262 | −2.168 | 59.429 | 76.020 | 1.00 | 40.88 | B | C |
| ATOM | 1219 | NH1 | ARG | B | 262 | −1.608 | 59.657 | 77.204 | 1.00 | 41.21 | B | N |
| ATOM | 1220 | NH2 | ARG | B | 262 | −2.451 | 58.184 | 75.652 | 1.00 | 41.01 | B | N |
| ATOM | 1221 | C | ARG | B | 262 | 1.736 | 63.284 | 73.701 | 1.00 | 14.39 | B | C |
| ATOM | 1222 | O | ARG | B | 262 | 1.627 | 64.505 | 73.777 | 1.00 | 14.91 | B | O |
| ATOM | 1223 | N | ARG | B | 263 | 2.761 | 62.625 | 74.233 | 1.00 | 11.59 | B | N |
| ATOM | 1224 | CA | ARG | B | 263 | 3.813 | 63.331 | 74.956 | 1.00 | 11.65 | B | C |
| ATOM | 1225 | CB | ARG | B | 263 | 4.817 | 62.330 | 75.534 | 1.00 | 11.59 | B | C |
| ATOM | 1226 | CG | ARG | B | 263 | 4.228 | 61.346 | 76.569 | 1.00 | 12.75 | B | C |
| ATOM | 1227 | CD | ARG | B | 263 | 3.330 | 62.026 | 77.624 | 1.00 | 9.55 | B | C |
| ATOM | 1228 | NE | ARG | B | 263 | 3.986 | 63.150 | 78.285 | 1.00 | 10.16 | B | N |
| ATOM | 1229 | CZ | ARG | B | 263 | 3.337 | 64.125 | 78.913 | 1.00 | 11.09 | B | C |
| ATOM | 1230 | NH1 | ARG | B | 263 | 2.018 | 64.111 | 78.967 | 1.00 | 13.12 | B | N |
| ATOM | 1231 | NH2 | ARG | B | 263 | 4.002 | 65.132 | 79.470 | 1.00 | 11.79 | B | N |
| ATOM | 1232 | C | ARG | B | 263 | 4.534 | 64.344 | 74.063 | 1.00 | 13.00 | B | C |
| ATOM | 1233 | O | ARG | B | 263 | 4.871 | 65.448 | 74.502 | 1.00 | 12.77 | B | O |
| ATOM | 1234 | N | LEU | B | 264 | 4.760 | 63.975 | 72.804 | 1.00 | 13.53 | B | N |
| ATOM | 1235 | CA | LEU | B | 264 | 5.427 | 64.865 | 71.851 | 1.00 | 13.37 | B | C |
| ATOM | 1236 | CB | LEU | B | 264 | 5.731 | 64.113 | 70.547 | 1.00 | 10.89 | B | C |
| ATOM | 1237 | CG | LEU | B | 264 | 6.863 | 63.084 | 70.680 | 1.00 | 8.87 | B | C |
| ATOM | 1238 | CD1 | LEU | B | 264 | 6.834 | 62.118 | 69.516 | 1.00 | 8.25 | B | C |
| ATOM | 1239 | CD2 | LEU | B | 264 | 8.207 | 63.801 | 70.755 | 1.00 | 7.81 | B | C |
| ATOM | 1240 | C | LEU | B | 264 | 4.557 | 66.091 | 71.575 | 1.00 | 12.79 | B | C |
| ATOM | 1241 | O | LEU | B | 264 | 5.057 | 67.204 | 71.422 | 1.00 | 12.60 | B | O |
| ATOM | 1242 | N | LYS | B | 265 | 3.249 | 65.884 | 71.518 | 1.00 | 15.38 | B | N |
| ATOM | 1243 | CA | LYS | B | 265 | 2.321 | 66.987 | 71.295 | 1.00 | 16.13 | B | C |
| ATOM | 1244 | CB | LYS | B | 265 | 0.890 | 66.463 | 71.191 | 1.00 | 18.28 | B | C |
| ATOM | 1245 | CG | LYS | B | 265 | 0.482 | 66.027 | 69.791 | 1.00 | 24.04 | B | C |
| ATOM | 1246 | CD | LYS | B | 265 | −0.700 | 65.057 | 69.830 | 1.00 | 27.74 | B | C |
| ATOM | 1247 | CE | LYS | B | 265 | −2.037 | 65.786 | 69.993 | 1.00 | 29.63 | B | C |
| ATOM | 1248 | NZ | LYS | B | 265 | −3.119 | 64.921 | 70.577 | 1.00 | 30.34 | B | N |
| ATOM | 1249 | C | LYS | B | 265 | 2.436 | 67.929 | 72.489 | 1.00 | 17.37 | B | C |
| ATOM | 1250 | O | LYS | B | 265 | 2.447 | 69.153 | 72.326 | 1.00 | 18.75 | B | O |
| ATOM | 1251 | N | PHE | B | 266 | 2.527 | 67.355 | 73.690 | 1.00 | 16.71 | B | N |
| ATOM | 1252 | CA | PHE | B | 266 | 2.651 | 68.167 | 74.898 | 1.00 | 15.39 | B | C |
| ATOM | 1253 | CB | PHE | B | 266 | 2.586 | 67.296 | 76.162 | 1.00 | 16.18 | B | C |
| ATOM | 1254 | CG | PHE | B | 266 | 2.734 | 68.085 | 77.437 | 1.00 | 15.85 | B | C |
| ATOM | 1255 | CD1 | PHE | B | 266 | 1.654 | 68.787 | 77.965 | 1.00 | 14.94 | B | C |
| ATOM | 1256 | CD2 | PHE | B | 266 | 3.969 | 68.183 | 78.073 | 1.00 | 14.91 | B | C |
| ATOM | 1257 | CE1 | PHE | B | 266 | 1.803 | 69.581 | 79.105 | 1.00 | 14.36 | B | C |
| ATOM | 1258 | CE2 | PHE | B | 266 | 4.123 | 68.976 | 79.215 | 1.00 | 16.04 | B | C |
| ATOM | 1259 | CZ | PHE | B | 266 | 3.039 | 69.676 | 79.728 | 1.00 | 13.75 | B | C |
| ATOM | 1260 | C | PHE | B | 266 | 3.964 | 68.954 | 74.884 | 1.00 | 13.64 | B | C |
| ATOM | 1261 | O | PHE | B | 266 | 3.988 | 70.147 | 75.190 | 1.00 | 13.91 | B | O |
| ATOM | 1262 | N | LEU | B | 267 | 5.054 | 68.282 | 74.530 | 1.00 | 12.68 | B | N |
| ATOM | 1263 | CA | LEU | B | 267 | 6.362 | 68.924 | 74.463 | 1.00 | 12.41 | B | C |
| ATOM | 1264 | CB | LEU | B | 267 | 7.391 | 67.930 | 73.928 | 1.00 | 13.00 | B | C |
| ATOM | 1265 | CG | LEU | B | 267 | 8.440 | 67.268 | 74.836 | 1.00 | 13.77 | B | C |
| ATOM | 1266 | CD1 | LEU | B | 267 | 8.051 | 67.364 | 76.298 | 1.00 | 12.21 | B | C |
| ATOM | 1267 | CD2 | LEU | B | 267 | 8.601 | 65.819 | 74.412 | 1.00 | 11.10 | B | C |
| ATOM | 1268 | C | LEU | B | 267 | 6.304 | 70.152 | 73.543 | 1.00 | 14.15 | B | C |
| ATOM | 1269 | O | LEU | B | 267 | 6.936 | 71.181 | 73.808 | 1.00 | 13.97 | B | O |
| ATOM | 1270 | N | SER | B | 268 | 5.530 | 70.029 | 72.464 | 1.00 | 14.24 | B | N |
| ATOM | 1271 | CA | SER | B | 268 | 5.358 | 71.095 | 71.481 | 1.00 | 11.86 | B | C |
| ATOM | 1272 | CB | SER | B | 268 | 4.655 | 70.535 | 70.245 | 1.00 | 12.78 | B | C |
| ATOM | 1273 | OG | SER | B | 268 | 4.561 | 71.508 | 69.221 | 1.00 | 15.89 | B | O |
| ATOM | 1274 | C | SER | B | 268 | 4.552 | 72.268 | 72.041 | 1.00 | 11.50 | B | C |
| ATOM | 1275 | O | SER | B | 268 | 5.009 | 73.409 | 72.020 | 1.00 | 11.13 | B | O |
| ATOM | 1276 | N | SER | B | 269 | 3.349 | 71.991 | 72.537 | 1.00 | 10.78 | B | N |
| ATOM | 1277 | CA | SER | B | 269 | 2.506 | 73.044 | 73.106 | 1.00 | 10.56 | B | C |
| ATOM | 1278 | CB | SER | B | 269 | 1.169 | 72.470 | 73.562 | 1.00 | 10.44 | B | C |
| ATOM | 1279 | OG | SER | B | 269 | 0.454 | 71.891 | 72.490 | 1.00 | 11.52 | B | O |
| ATOM | 1280 | C | SER | B | 269 | 3.183 | 73.731 | 74.294 | 1.00 | 12.18 | B | C |
| ATOM | 1281 | O | SER | B | 269 | 3.113 | 74.953 | 74.438 | 1.00 | 12.67 | B | O |
| ATOM | 1282 | N | LYS | B | 270 | 3.836 | 72.952 | 75.153 | 1.00 | 12.94 | B | N |
| ATOM | 1283 | CA | LYS | B | 270 | 4.501 | 73.544 | 76.303 | 1.00 | 13.84 | B | C |
| ATOM | 1284 | CB | LYS | B | 270 | 5.205 | 72.476 | 77.152 | 1.00 | 14.79 | B | C |
| ATOM | 1285 | CG | LYS | B | 270 | 5.350 | 72.883 | 78.625 | 1.00 | 12.65 | B | C |
| ATOM | 1286 | CD | LYS | B | 270 | 6.387 | 72.045 | 79.357 | 1.00 | 10.48 | B | C |
| ATOM | 1287 | CE | LYS | B | 270 | 6.827 | 72.719 | 80.660 | 1.00 | 11.37 | B | C |
| ATOM | 1288 | NZ | LYS | B | 270 | 7.892 | 71.932 | 81.374 | 1.00 | 12.57 | B | N |
| ATOM | 1289 | C | LYS | B | 270 | 5.505 | 74.600 | 75.879 | 1.00 | 13.38 | B | C |
| ATOM | 1290 | O | LYS | B | 270 | 5.560 | 75.678 | 76.465 | 1.00 | 14.81 | B | O |
| ATOM | 1291 | N | PHE | B | 271 | 6.302 | 74.308 | 74.858 | 1.00 | 14.85 | B | N |
| ATOM | 1292 | CA | PHE | B | 271 | 7.282 | 75.292 | 74.405 | 1.00 | 14.12 | B | C |
| ATOM | 1293 | CB | PHE | B | 271 | 8.159 | 74.729 | 73.281 | 1.00 | 12.55 | B | C |
| ATOM | 1294 | CG | PHE | B | 271 | 9.293 | 75.635 | 72.908 | 1.00 | 11.13 | B | C |
| ATOM | 1295 | CD1 | PHE | B | 271 | 10.445 | 75.684 | 73.692 | 1.00 | 10.79 | B | C |
| ATOM | 1296 | CD2 | PHE | B | 271 | 9.187 | 76.493 | 71.814 | 1.00 | 11.27 | B | C |
| ATOM | 1297 | CE1 | PHE | B | 271 | 11.478 | 76.581 | 73.395 | 1.00 | 11.03 | B | C |
| ATOM | 1298 | CE2 | PHE | B | 271 | 10.214 | 77.395 | 71.508 | 1.00 | 10.94 | B | C |
| ATOM | 1299 | CZ | PHE | B | 271 | 11.361 | 77.439 | 72.303 | 1.00 | 9.40 | B | C |
| ATOM | 1300 | C | PHE | B | 271 | 6.624 | 76.577 | 73.922 | 1.00 | 14.31 | B | C |
| ATOM | 1301 | O | PHE | B | 271 | 7.131 | 77.671 | 74.162 | 1.00 | 16.41 | B | O |
| ATOM | 1302 | N | GLN | B | 272 | 5.496 | 76.440 | 73.236 | 1.00 | 16.51 | B | N |
| ATOM | 1303 | CA | GLN | B | 272 | 4.772 | 77.595 | 72.709 | 1.00 | 17.54 | B | C |
| ATOM | 1304 | CB | GLN | B | 272 | 3.573 | 77.124 | 71.887 | 1.00 | 18.70 | B | C |
| ATOM | 1305 | CG | GLN | B | 272 | 3.760 | 77.300 | 70.396 | 1.00 | 25.67 | B | C |
| ATOM | 1306 | CD | GLN | B | 272 | 3.947 | 75.984 | 69.673 | 1.00 | 29.02 | B | C |
| ATOM | 1307 | OE1 | GLN | B | 272 | 2.979 | 75.362 | 69.222 | 1.00 | 29.54 | B | O |
| ATOM | 1308 | NE2 | GLN | B | 272 | 5.200 | 75.550 | 69.553 | 1.00 | 30.92 | B | N |
| ATOM | 1309 | C | GLN | B | 272 | 4.296 | 78.527 | 73.821 | 1.00 | 15.82 | B | C |
| ATOM | 1310 | O | GLN | B | 272 | 4.399 | 79.748 | 73.711 | 1.00 | 14.46 | B | O |
| ATOM | 1311 | N | VAL | B | 273 | 3.759 | 77.951 | 74.889 | 1.00 | 14.46 | B | N |
| ATOM | 1312 | CA | VAL | B | 273 | 3.290 | 78.765 | 75.993 | 1.00 | 13.52 | B | C |
| ATOM | 1313 | CB | VAL | B | 273 | 2.450 | 77.926 | 76.981 | 1.00 | 13.56 | B | C |
| ATOM | 1314 | CG1 | VAL | B | 273 | 2.067 | 78.767 | 78.191 | 1.00 | 14.77 | B | C |
| ATOM | 1315 | CG2 | VAL | B | 273 | 1.199 | 77.413 | 76.279 | 1.00 | 13.24 | B | C |
| ATOM | 1316 | C | VAL | B | 273 | 4.498 | 79.380 | 76.698 | 1.00 | 13.45 | B | C |
| ATOM | 1317 | O | VAL | B | 273 | 4.471 | 80.551 | 77.079 | 1.00 | 14.11 | B | O |
| ATOM | 1318 | N | HIS | B | 274 | 5.566 | 78.599 | 76.851 | 1.00 | 14.15 | B | N |
| ATOM | 1319 | CA | HIS | B | 274 | 6.776 | 79.098 | 77.499 | 1.00 | 15.36 | B | C |
| ATOM | 1320 | CB | HIS | B | 274 | 7.854 | 78.011 | 77.539 | 1.00 | 12.81 | B | C |
| ATOM | 1321 | CG | HIS | B | 274 | 9.228 | 78.534 | 77.828 | 1.00 | 11.79 | B | C |
| ATOM | 1322 | CD2 | HIS | B | 274 | 10.318 | 78.667 | 77.036 | 1.00 | 11.82 | B | C |
| ATOM | 1323 | ND1 | HIS | B | 274 | 9.598 | 79.008 | 79.068 | 1.00 | 12.44 | B | N |
| ATOM | 1324 | CE1 | HIS | B | 274 | 10.856 | 79.412 | 79.027 | 1.00 | 13.35 | B | C |
| ATOM | 1325 | NE2 | HIS | B | 274 | 11.316 | 79.215 | 77.805 | 1.00 | 13.41 | B | N |
| ATOM | 1326 | C | HIS | B | 274 | 7.313 | 80.308 | 76.741 | 1.00 | 19.06 | B | C |
| ATOM | 1327 | O | HIS | B | 274 | 7.617 | 81.350 | 77.331 | 1.00 | 19.47 | B | O |
| ATOM | 1328 | N | GLN | B | 275 | 7.424 | 80.171 | 75.426 | 1.00 | 21.40 | B | N |
| ATOM | 1329 | CA | GLN | B | 275 | 7.940 | 81.256 | 74.605 | 1.00 | 24.06 | B | C |
| ATOM | 1330 | CB | GLN | B | 275 | 8.123 | 80.793 | 73.157 | 1.00 | 28.45 | B | C |
| ATOM | 1331 | CG | GLN | B | 275 | 9.576 | 80.802 | 72.702 | 1.00 | 36.28 | B | C |
| ATOM | 1332 | CD | GLN | B | 275 | 9.717 | 80.783 | 71.182 | 1.00 | 41.53 | B | C |
| ATOM | 1333 | OE1 | GLN | B | 275 | 8.723 | 80.886 | 70.450 | 1.00 | 43.21 | B | O |
| ATOM | 1334 | NE2 | GLN | B | 275 | 10.958 | 80.655 | 70.700 | 1.00 | 41.01 | B | N |
| ATOM | 1335 | C | GLN | B | 275 | 7.062 | 82.493 | 74.635 | 1.00 | 23.43 | B | C |
| ATOM | 1336 | O | GLN | B | 275 | 7.564 | 83.612 | 74.750 | 1.00 | 24.46 | B | O |
| ATOM | 1337 | N | MET | B | 276 | 5.753 | 82.311 | 74.537 | 1.00 | 22.52 | B | N |
| ATOM | 1338 | CA | MET | B | 276 | 4.880 | 83.469 | 74.542 | 1.00 | 24.42 | B | C |
| ATOM | 1339 | CB | MET | B | 276 | 3.475 | 83.081 | 74.080 | 1.00 | 25.80 | B | C |
| ATOM | 1340 | CG | MET | B | 276 | 2.579 | 82.491 | 75.138 | 1.00 | 28.27 | B | C |
| ATOM | 1341 | SD | MET | B | 276 | 0.961 | 82.081 | 74.424 | 1.00 | 32.71 | B | S |
| ATOM | 1342 | CE | MET | B | 276 | 1.338 | 80.605 | 73.469 | 1.00 | 29.97 | B | C |
| ATOM | 1343 | C | MET | B | 276 | 4.839 | 84.137 | 75.909 | 1.00 | 23.44 | B | C |
| ATOM | 1344 | O | MET | B | 276 | 4.585 | 85.335 | 76.010 | 1.00 | 24.96 | B | O |
| ATOM | 1345 | N | LEU | B | 277 | 5.122 | 83.371 | 76.955 | 1.00 | 21.65 | B | N |
| ATOM | 1346 | CA | LEU | B | 277 | 5.113 | 83.911 | 78.311 | 1.00 | 20.73 | B | C |
| ATOM | 1347 | CB | LEU | B | 277 | 4.676 | 82.821 | 79.295 | 1.00 | 19.81 | B | C |
| ATOM | 1348 | CG | LEU | B | 277 | 3.320 | 82.830 | 79.999 | 1.00 | 19.49 | B | C |
| ATOM | 1349 | CD1 | LEU | B | 277 | 2.258 | 83.535 | 79.179 | 1.00 | 18.74 | B | C |
| ATOM | 1350 | CD2 | LEU | B | 277 | 2.926 | 81.383 | 80.247 | 1.00 | 20.65 | B | C |
| ATOM | 1351 | C | LEU | B | 277 | 6.473 | 84.459 | 78.771 | 1.00 | 19.63 | B | C |
| ATOM | 1352 | O | LEU | B | 277 | 6.527 | 85.429 | 79.532 | 1.00 | 20.30 | B | O |
| ATOM | 1353 | N | ASN | B | 278 | 7.565 | 83.852 | 78.299 | 1.00 | 17.69 | B | N |
| ATOM | 1354 | CA | ASN | B | 278 | 8.900 | 84.247 | 78.749 | 1.00 | 16.29 | B | C |
| ATOM | 1355 | CB | ASN | B | 278 | 9.448 | 83.134 | 79.647 | 1.00 | 16.89 | B | C |
| ATOM | 1356 | CG | ASN | B | 278 | 8.464 | 82.726 | 80.726 | 1.00 | 15.75 | B | C |
| ATOM | 1357 | OD1 | ASN | B | 278 | 7.987 | 81.590 | 80.755 | 1.00 | 17.44 | B | O |
| ATOM | 1358 | ND2 | ASN | B | 278 | 8.146 | 83.658 | 81.616 | 1.00 | 15.03 | B | N |
| ATOM | 1359 | C | ASN | B | 278 | 9.989 | 84.644 | 77.752 | 1.00 | 16.45 | B | C |
| ATOM | 1360 | O | ASN | B | 278 | 11.139 | 84.860 | 78.158 | 1.00 | 14.67 | B | O |
| ATOM | 1361 | N | GLU | B | 279 | 9.660 | 84.754 | 76.467 | 1.00 | 16.52 | B | N |
| ATOM | 1362 | CA | GLU | B | 279 | 10.675 | 85.123 | 75.478 | 1.00 | 16.83 | B | C |
| ATOM | 1363 | CB | GLU | B | 279 | 10.069 | 85.130 | 74.078 | 1.00 | 17.45 | B | C |
| ATOM | 1364 | CG | GLU | B | 279 | 8.882 | 86.054 | 73.918 | 1.00 | 21.99 | B | C |
| ATOM | 1365 | CD | GLU | B | 279 | 8.402 | 86.120 | 72.490 | 1.00 | 25.29 | B | C |
| ATOM | 1366 | OE1 | GLU | B | 279 | 9.238 | 85.951 | 71.581 | 1.00 | 28.68 | B | O |
| ATOM | 1367 | OE2 | GLU | B | 279 | 7.193 | 86.340 | 72.273 | 1.00 | 29.26 | B | O |
| ATOM | 1368 | C | GLU | B | 279 | 11.341 | 86.470 | 75.768 | 1.00 | 14.95 | B | C |
| ATOM | 1369 | O | GLU | B | 279 | 12.545 | 86.621 | 75.583 | 1.00 | 15.57 | B | O |
| ATOM | 1370 | N | MET | B | 280 | 10.568 | 87.447 | 76.231 | 1.00 | 17.40 | B | N |
| ATOM | 1371 | CA | MET | B | 280 | 11.126 | 88.766 | 76.544 | 1.00 | 18.96 | B | C |
| ATOM | 1372 | CB | MET | B | 280 | 10.008 | 89.760 | 76.883 | 1.00 | 24.35 | B | C |
| ATOM | 1373 | CG | MET | B | 280 | 9.192 | 90.251 | 75.680 | 1.00 | 32.73 | B | C |
| ATOM | 1374 | SD | MET | B | 280 | 10.194 | 90.637 | 74.201 | 1.00 | 44.49 | B | S |
| ATOM | 1375 | CE | MET | B | 280 | 10.651 | 92.368 | 74.543 | 1.00 | 41.75 | B | C |
| ATOM | 1376 | C | MET | B | 280 | 12.086 | 88.658 | 77.723 | 1.00 | 19.10 | B | C |
| ATOM | 1377 | O | MET | B | 280 | 13.039 | 89.421 | 77.837 | 1.00 | 19.45 | B | O |
| ATOM | 1378 | N | ASP | B | 281 | 11.826 | 87.691 | 78.594 | 1.00 | 18.91 | B | N |
| ATOM | 1379 | CA | ASP | B | 281 | 12.651 | 87.462 | 79.765 | 1.00 | 18.06 | B | C |
| ATOM | 1380 | CB | ASP | B | 281 | 11.859 | 86.640 | 80.778 | 1.00 | 20.54 | B | C |
| ATOM | 1381 | CG | ASP | B | 281 | 10.657 | 87.400 | 81.300 | 1.00 | 21.40 | B | C |
| ATOM | 1382 | OD1 | ASP | B | 281 | 9.508 | 86.988 | 81.023 | 1.00 | 24.91 | B | O |
| ATOM | 1383 | OD2 | ASP | B | 281 | 10.869 | 88.431 | 81.974 | 1.00 | 24.07 | B | O |
| ATOM | 1384 | C | ASP | B | 281 | 13.958 | 86.778 | 79.395 | 1.00 | 17.29 | B | C |
| ATOM | 1385 | O | ASP | B | 281 | 15.008 | 87.099 | 79.946 | 1.00 | 15.69 | B | O |
| ATOM | 1386 | N | GLU | B | 282 | 13.899 | 85.835 | 78.464 | 1.00 | 16.46 | B | N |
| ATOM | 1387 | CA | GLU | B | 282 | 15.117 | 85.168 | 78.020 | 1.00 | 15.20 | B | C |
| ATOM | 1388 | CB | GLU | B | 282 | 14.785 | 84.016 | 77.076 | 1.00 | 13.76 | B | C |
| ATOM | 1389 | CG | GLU | B | 282 | 14.106 | 82.856 | 77.767 | 1.00 | 12.66 | B | C |
| ATOM | 1390 | CD | GLU | B | 282 | 13.620 | 81.815 | 76.794 | 1.00 | 14.68 | B | C |
| ATOM | 1391 | OE1 | GLU | B | 282 | 13.186 | 82.205 | 75.694 | 1.00 | 15.28 | B | O |
| ATOM | 1392 | OE2 | GLU | B | 282 | 13.672 | 80.612 | 77.121 | 1.00 | 13.70 | B | O |
| ATOM | 1393 | C | GLU | B | 282 | 15.951 | 86.223 | 77.298 | 1.00 | 14.86 | B | C |
| ATOM | 1394 | O | GLU | B | 282 | 17.165 | 86.299 | 77.477 | 1.00 | 14.20 | B | O |
| ATOM | 1395 | N | LEU | B | 283 | 15.289 | 87.057 | 76.500 | 1.00 | 15.13 | B | N |
| ATOM | 1396 | CA | LEU | B | 283 | 15.981 | 88.113 | 75.766 | 1.00 | 15.78 | B | C |
| ATOM | 1397 | CB | LEU | B | 283 | 14.987 | 88.927 | 74.932 | 1.00 | 16.31 | B | C |
| ATOM | 1398 | CG | LEU | B | 283 | 15.420 | 89.546 | 73.588 | 1.00 | 18.96 | B | C |
| ATOM | 1399 | CD1 | LEU | B | 283 | 14.784 | 90.929 | 73.454 | 1.00 | 19.32 | B | C |
| ATOM | 1400 | CD2 | LEU | B | 283 | 16.932 | 89.637 | 73.466 | 1.00 | 15.03 | B | C |
| ATOM | 1401 | C | LEU | B | 283 | 16.710 | 89.049 | 76.726 | 1.00 | 16.87 | B | C |
| ATOM | 1402 | O | LEU | B | 283 | 17.855 | 89.448 | 76.480 | 1.00 | 16.95 | B | O |
| ATOM | 1403 | N | LYS | B | 284 | 16.039 | 89.410 | 77.815 | 1.00 | 17.96 | B | N |
| ATOM | 1404 | CA | LYS | B | 284 | 16.629 | 90.301 | 78.808 | 1.00 | 17.30 | B | C |
| ATOM | 1405 | CB | LYS | B | 284 | 15.657 | 90.502 | 79.974 | 1.00 | 20.19 | B | C |
| ATOM | 1406 | CG | LYS | B | 284 | 16.121 | 91.516 | 81.011 | 1.00 | 23.57 | B | C |
| ATOM | 1407 | CD | LYS | B | 284 | 15.176 | 91.562 | 82.211 | 1.00 | 26.74 | B | C |
| ATOM | 1408 | CE | LYS | B | 284 | 15.578 | 92.658 | 83.203 | 1.00 | 30.82 | B | C |
| ATOM | 1409 | NZ | LYS | B | 284 | 14.615 | 92.788 | 84.343 | 1.00 | 34.27 | B | N |
| ATOM | 1410 | C | LYS | B | 284 | 17.967 | 89.760 | 79.317 | 1.00 | 15.67 | B | C |
| ATOM | 1411 | O | LYS | B | 284 | 18.909 | 90.523 | 79.520 | 1.00 | 14.90 | B | O |
| ATOM | 1412 | N | GLU | B | 285 | 18.057 | 88.446 | 79.513 | 1.00 | 15.87 | B | N |
| ATOM | 1413 | CA | GLU | B | 285 | 19.299 | 87.838 | 79.985 | 1.00 | 14.91 | B | C |
| ATOM | 1414 | CB | GLU | B | 285 | 19.135 | 86.330 | 80.174 | 1.00 | 14.00 | B | C |
| ATOM | 1415 | CG | GLU | B | 285 | 18.318 | 85.912 | 81.385 | 1.00 | 15.39 | B | C |
| ATOM | 1416 | CD | GLU | B | 285 | 18.450 | 84.428 | 81.697 | 1.00 | 17.37 | B | C |
| ATOM | 1417 | OE1 | GLU | B | 285 | 19.568 | 83.988 | 82.051 | 1.00 | 19.28 | B | O |
| ATOM | 1418 | OE2 | GLU | B | 285 | 17.437 | 83.701 | 81.588 | 1.00 | 18.48 | B | O |
| ATOM | 1419 | C | GLU | B | 285 | 20.433 | 88.084 | 78.994 | 1.00 | 17.20 | B | C |
| ATOM | 1420 | O | GLU | B | 285 | 21.529 | 88.496 | 79.385 | 1.00 | 17.13 | B | O |
| ATOM | 1421 | N | LEU | B | 286 | 20.170 | 87.832 | 77.709 | 1.00 | 19.65 | B | N |
| ATOM | 1422 | CA | LEU | B | 286 | 21.187 | 88.023 | 76.669 | 1.00 | 19.97 | B | C |
| ATOM | 1423 | CB | LEU | B | 286 | 20.681 | 87.524 | 75.303 | 1.00 | 20.75 | B | C |
| ATOM | 1424 | CG | LEU | B | 286 | 20.000 | 86.155 | 75.130 | 1.00 | 20.64 | B | C |
| ATOM | 1425 | CD1 | LEU | B | 286 | 20.502 | 85.549 | 73.840 | 1.00 | 22.32 | B | C |
| ATOM | 1426 | CD2 | LEU | B | 286 | 20.267 | 85.219 | 76.288 | 1.00 | 19.75 | B | C |
| ATOM | 1427 | C | LEU | B | 286 | 21.596 | 89.491 | 76.548 | 1.00 | 19.07 | B | C |
| ATOM | 1428 | O | LEU | B | 286 | 22.779 | 89.805 | 76.415 | 1.00 | 18.43 | B | O |
| ATOM | 1429 | N | LYS | B | 287 | 20.611 | 90.386 | 76.586 | 1.00 | 20.34 | B | N |
| ATOM | 1430 | CA | LYS | B | 287 | 20.879 | 91.818 | 76.494 | 1.00 | 21.47 | B | C |
| ATOM | 1431 | CB | LYS | B | 287 | 19.574 | 92.603 | 76.556 | 1.00 | 21.05 | B | C |
| ATOM | 1432 | CG | LYS | B | 287 | 18.878 | 92.781 | 75.227 | 1.00 | 22.86 | B | C |
| ATOM | 1433 | CD | LYS | B | 287 | 17.407 | 93.087 | 75.440 | 1.00 | 23.59 | B | C |
| ATOM | 1434 | CE | LYS | B | 287 | 16.995 | 94.372 | 74.748 | 1.00 | 25.89 | B | C |
| ATOM | 1435 | NZ | LYS | B | 287 | 15.522 | 94.407 | 74.497 | 1.00 | 28.34 | B | N |
| ATOM | 1436 | C | LYS | B | 287 | 21.783 | 92.275 | 77.640 | 1.00 | 23.06 | B | C |
| ATOM | 1437 | O | LYS | B | 287 | 22.659 | 93.123 | 77.459 | 1.00 | 22.71 | B | O |
| ATOM | 1438 | N | ASN | B | 288 | 21.560 | 91.710 | 78.822 | 1.00 | 24.00 | B | N |
| ATOM | 1439 | CA | ASN | B | 288 | 22.347 | 92.067 | 79.998 | 1.00 | 25.55 | B | C |
| ATOM | 1440 | CB | ASN | B | 288 | 21.509 | 91.888 | 81.262 | 1.00 | 23.86 | B | C |
| ATOM | 1441 | CG | ASN | B | 288 | 20.497 | 92.997 | 81.436 | 1.00 | 26.49 | B | C |
| ATOM | 1442 | OD1 | ASN | B | 288 | 20.790 | 94.168 | 81.178 | 1.00 | 27.19 | B | O |
| ATOM | 1443 | ND2 | ASN | B | 288 | 19.297 | 92.638 | 81.867 | 1.00 | 26.82 | B | N |
| ATOM | 1444 | C | ASN | B | 288 | 23.640 | 91.275 | 80.107 | 1.00 | 25.61 | B | C |
| ATOM | 1445 | O | ASN | B | 288 | 24.339 | 91.343 | 81.114 | 1.00 | 25.17 | B | O |
| ATOM | 1446 | N | ASN | B | 289 | 23.951 | 90.526 | 79.057 | 1.00 | 25.96 | B | N |
| ATOM | 1447 | CA | ASN | B | 289 | 25.171 | 89.735 | 78.998 | 1.00 | 27.46 | B | C |
| ATOM | 1448 | CB | ASN | B | 289 | 24.847 | 88.341 | 78.463 | 1.00 | 23.73 | B | C |
| ATOM | 1449 | CG | ASN | B | 289 | 26.030 | 87.413 | 78.508 | 1.00 | 21.57 | B | C |
| ATOM | 1450 | OD1 | ASN | B | 289 | 26.863 | 87.492 | 79.407 | 1.00 | 20.78 | B | O |
| ATOM | 1451 | ND2 | ASN | B | 289 | 26.115 | 86.523 | 77.529 | 1.00 | 18.71 | B | N |
| ATOM | 1452 | C | ASN | B | 289 | 26.107 | 90.484 | 78.044 | 1.00 | 30.37 | B | C |
| ATOM | 1453 | O | ASN | B | 289 | 26.043 | 90.293 | 76.825 | 1.00 | 33.00 | B | O |
| ATOM | 1454 | N | PRO | B | 290 | 26.982 | 91.355 | 78.586 | 1.00 | 32.27 | B | N |
| ATOM | 1455 | CD | PRO | B | 290 | 27.138 | 91.625 | 80.027 | 1.00 | 30.92 | B | C |
| ATOM | 1456 | CA | PRO | B | 290 | 27.928 | 92.147 | 77.785 | 1.00 | 32.58 | B | C |
| ATOM | 1457 | CB | PRO | B | 290 | 28.438 | 93.191 | 78.772 | 1.00 | 31.53 | B | C |
| ATOM | 1458 | CG | PRO | B | 290 | 28.379 | 92.478 | 80.082 | 1.00 | 31.79 | B | C |
| ATOM | 1459 | C | PRO | B | 290 | 29.071 | 91.345 | 77.176 | 1.00 | 33.33 | B | C |
| ATOM | 1460 | O | PRO | B | 290 | 29.781 | 91.823 | 76.288 | 1.00 | 33.44 | B | O |
| ATOM | 1461 | N | HIS | B | 291 | 29.245 | 90.124 | 77.655 | 1.00 | 34.72 | B | N |
| ATOM | 1462 | CA | HIS | B | 291 | 30.319 | 89.270 | 77.166 | 1.00 | 38.49 | B | C |
| ATOM | 1463 | CB | HIS | B | 291 | 30.576 | 88.142 | 78.170 | 1.00 | 42.40 | B | C |
| ATOM | 1464 | CG | HIS | B | 291 | 30.908 | 88.631 | 79.544 | 1.00 | 47.53 | B | C |
| ATOM | 1465 | CD2 | HIS | B | 291 | 32.101 | 88.823 | 80.158 | 1.00 | 48.49 | B | C |
| ATOM | 1466 | ND1 | HIS | B | 291 | 29.943 | 89.028 | 80.446 | 1.00 | 50.36 | B | N |
| ATOM | 1467 | CE1 | HIS | B | 291 | 30.528 | 89.444 | 81.556 | 1.00 | 51.37 | B | C |
| ATOM | 1468 | NE2 | HIS | B | 291 | 31.837 | 89.330 | 81.407 | 1.00 | 50.88 | B | N |
| ATOM | 1469 | C | HIS | B | 291 | 30.068 | 88.667 | 75.789 | 1.00 | 36.89 | B | C |
| ATOM | 1470 | O | HIS | B | 291 | 31.012 | 88.349 | 75.067 | 1.00 | 37.34 | B | O |
| ATOM | 1471 | N | ARG | B | 292 | 28.805 | 88.530 | 75.408 | 1.00 | 33.25 | B | N |
| ATOM | 1472 | CA | ARG | B | 292 | 28.522 | 87.901 | 74.141 | 1.00 | 29.48 | B | C |
| ATOM | 1473 | CB | ARG | B | 292 | 28.561 | 86.381 | 74.336 | 1.00 | 27.45 | B | C |
| ATOM | 1474 | CG | ARG | B | 292 | 29.793 | 85.720 | 73.784 | 1.00 | 28.15 | B | C |
| ATOM | 1475 | CD | ARG | B | 292 | 30.199 | 84.560 | 74.632 | 1.00 | 29.09 | B | C |
| ATOM | 1476 | NE | ARG | B | 292 | 31.506 | 84.766 | 75.248 | 1.00 | 30.25 | B | N |
| ATOM | 1477 | CZ | ARG | B | 292 | 32.660 | 84.781 | 74.587 | 1.00 | 29.11 | B | C |
| ATOM | 1478 | NH1 | ARG | B | 292 | 32.692 | 84.604 | 73.274 | 1.00 | 30.36 | B | N |
| ATOM | 1479 | NH2 | ARG | B | 292 | 33.792 | 84.964 | 75.244 | 1.00 | 30.37 | B | N |
| ATOM | 1480 | C | ARG | B | 292 | 27.220 | 88.252 | 73.448 | 1.00 | 27.42 | B | C |
| ATOM | 1481 | O | ARG | B | 292 | 26.285 | 88.819 | 74.039 | 1.00 | 27.46 | B | O |
| ATOM | 1482 | N | ASP | B | 293 | 27.207 | 87.897 | 72.165 | 1.00 | 24.62 | B | N |
| ATOM | 1483 | CA | ASP | B | 293 | 26.061 | 88.013 | 71.277 | 1.00 | 22.14 | B | C |
| ATOM | 1484 | CB | ASP | B | 293 | 25.988 | 89.374 | 70.567 | 1.00 | 19.74 | B | C |
| ATOM | 1485 | CG | ASP | B | 293 | 27.186 | 89.664 | 69.700 | 1.00 | 21.87 | B | C |
| ATOM | 1486 | OD1 | ASP | B | 293 | 27.460 | 90.865 | 69.497 | 1.00 | 22.08 | B | O |
| ATOM | 1487 | OD2 | ASP | B | 293 | 27.846 | 88.719 | 69.219 | 1.00 | 22.23 | B | O |
| ATOM | 1488 | C | ASP | B | 293 | 26.300 | 86.859 | 70.307 | 1.00 | 20.50 | B | C |
| ATOM | 1489 | O | ASP | B | 293 | 27.361 | 86.240 | 70.344 | 1.00 | 19.07 | B | O |
| ATOM | 1490 | N | PHE | B | 294 | 25.324 | 86.543 | 69.465 | 1.00 | 22.43 | B | N |
| ATOM | 1491 | CA | PHE | B | 294 | 25.466 | 85.420 | 68.544 | 1.00 | 21.72 | B | C |
| ATOM | 1492 | CB | PHE | B | 294 | 24.309 | 85.408 | 67.547 | 1.00 | 22.30 | B | C |
| ATOM | 1493 | CG | PHE | B | 294 | 24.383 | 84.282 | 66.548 | 1.00 | 23.36 | B | C |
| ATOM | 1494 | CD1 | PHE | B | 294 | 24.022 | 82.988 | 66.912 | 1.00 | 21.82 | B | C |
| ATOM | 1495 | CD2 | PHE | B | 294 | 24.832 | 84.512 | 65.253 | 1.00 | 22.27 | B | C |
| ATOM | 1496 | CE1 | PHE | B | 294 | 24.108 | 81.936 | 66.004 | 1.00 | 20.20 | B | C |
| ATOM | 1497 | CE2 | PHE | B | 294 | 24.922 | 83.464 | 64.339 | 1.00 | 21.39 | B | C |
| ATOM | 1498 | CZ | PHE | B | 294 | 24.559 | 82.175 | 64.717 | 1.00 | 21.21 | B | C |
| ATOM | 1499 | C | PHE | B | 294 | 26.781 | 85.394 | 67.780 | 1.00 | 21.26 | B | C |
| ATOM | 1500 | O | PHE | B | 294 | 27.382 | 84.341 | 67.597 | 1.00 | 22.30 | B | O |
| ATOM | 1501 | N | TYR | B | 295 | 27.232 | 86.562 | 67.350 | 1.00 | 20.44 | B | N |
| ATOM | 1502 | CA | TYR | B | 295 | 28.449 | 86.654 | 66.568 | 1.00 | 20.22 | B | C |
| ATOM | 1503 | CB | TYR | B | 295 | 28.563 | 88.062 | 66.014 | 1.00 | 20.44 | B | C |
| ATOM | 1504 | CG | TYR | B | 295 | 27.417 | 88.326 | 65.084 | 1.00 | 23.19 | B | C |
| ATOM | 1505 | CD1 | TYR | B | 295 | 27.377 | 87.739 | 63.819 | 1.00 | 24.15 | B | C |
| ATOM | 1506 | CE1 | TYR | B | 295 | 26.275 | 87.899 | 62.985 | 1.00 | 25.40 | B | C |
| ATOM | 1507 | CD2 | TYR | B | 295 | 26.324 | 89.085 | 65.493 | 1.00 | 23.96 | B | C |
| ATOM | 1508 | CE2 | TYR | B | 295 | 25.215 | 89.253 | 64.665 | 1.00 | 24.99 | B | C |
| ATOM | 1509 | CZ | TYR | B | 295 | 25.198 | 88.657 | 63.414 | 1.00 | 26.74 | B | C |
| ATOM | 1510 | OH | TYR | B | 295 | 24.113 | 88.835 | 62.585 | 1.00 | 28.56 | B | O |
| ATOM | 1511 | C | TYR | B | 295 | 29.760 | 86.202 | 67.180 | 1.00 | 20.55 | B | C |
| ATOM | 1512 | O | TYR | B | 295 | 30.673 | 85.848 | 66.447 | 1.00 | 22.69 | B | O |
| ATOM | 1513 | N | ASN | B | 296 | 29.888 | 86.206 | 68.501 | 1.00 | 19.23 | B | N |
| ATOM | 1514 | CA | ASN | B | 296 | 31.138 | 85.727 | 69.070 | 1.00 | 17.55 | B | C |
| ATOM | 1515 | CB | ASN | B | 296 | 31.910 | 86.847 | 69.797 | 1.00 | 19.40 | B | C |
| ATOM | 1516 | CG | ASN | B | 296 | 31.191 | 87.398 | 71.011 | 1.00 | 19.47 | B | C |
| ATOM | 1517 | OD1 | ASN | B | 296 | 31.805 | 88.088 | 71.820 | 1.00 | 18.48 | B | O |
| ATOM | 1518 | ND2 | ASN | B | 296 | 29.899 | 87.110 | 71.143 | 1.00 | 21.34 | B | N |
| ATOM | 1519 | C | ASN | B | 296 | 30.959 | 84.491 | 69.941 | 1.00 | 17.58 | B | C |
| ATOM | 1520 | O | ASN | B | 296 | 31.711 | 84.249 | 70.886 | 1.00 | 16.39 | B | O |
| ATOM | 1521 | N | CYS | B | 297 | 29.942 | 83.710 | 69.585 | 1.00 | 16.66 | B | N |
| ATOM | 1522 | CA | CYS | B | 297 | 29.636 | 82.433 | 70.220 | 1.00 | 19.23 | B | C |
| ATOM | 1523 | CB | CYS | B | 297 | 28.124 | 82.174 | 70.233 | 1.00 | 20.42 | B | C |
| ATOM | 1524 | SG | CYS | B | 297 | 27.214 | 82.956 | 71.586 | 1.00 | 24.81 | B | S |
| ATOM | 1525 | C | CYS | B | 297 | 30.284 | 81.443 | 69.253 | 1.00 | 18.17 | B | C |
| ATOM | 1526 | O | CYS | B | 297 | 30.341 | 81.708 | 68.053 | 1.00 | 19.17 | B | O |
| ATOM | 1527 | N | ARG | B | 298 | 30.783 | 80.321 | 69.749 | 1.00 | 18.02 | B | N |
| ATOM | 1528 | CA | ARG | B | 298 | 31.384 | 79.349 | 68.850 | 1.00 | 18.29 | B | C |
| ATOM | 1529 | CB | ARG | B | 298 | 32.302 | 78.400 | 69.613 | 1.00 | 19.88 | B | C |
| ATOM | 1530 | CG | ARG | B | 298 | 33.750 | 78.827 | 69.613 | 1.00 | 21.35 | B | C |
| ATOM | 1531 | CD | ARG | B | 298 | 33.918 | 80.106 | 70.405 | 1.00 | 22.72 | B | C |
| ATOM | 1532 | NE | ARG | B | 298 | 35.322 | 80.460 | 70.564 | 1.00 | 25.61 | B | N |
| ATOM | 1533 | CZ | ARG | B | 298 | 35.756 | 81.422 | 71.373 | 1.00 | 27.85 | B | C |
| ATOM | 1534 | NH1 | ARG | B | 298 | 34.891 | 82.123 | 72.097 | 1.00 | 28.66 | B | N |
| ATOM | 1535 | NH2 | ARG | B | 298 | 37.052 | 81.692 | 71.453 | 1.00 | 28.43 | B | N |
| ATOM | 1536 | C | ARG | B | 298 | 30.274 | 78.553 | 68.179 | 1.00 | 19.67 | B | C |
| ATOM | 1537 | O | ARG | B | 298 | 29.252 | 78.243 | 68.805 | 1.00 | 18.89 | B | O |
| ATOM | 1538 | N | LYS | B | 299 | 30.474 | 78.245 | 66.899 | 1.00 | 19.52 | B | N |
| ATOM | 1539 | CA | LYS | B | 299 | 29.511 | 77.478 | 66.108 | 1.00 | 17.98 | B | C |
| ATOM | 1540 | CB | LYS | B | 299 | 28.858 | 78.370 | 65.053 | 1.00 | 18.44 | B | C |
| ATOM | 1541 | CG | LYS | B | 299 | 27.534 | 78.984 | 65.473 | 1.00 | 20.31 | B | C |
| ATOM | 1542 | CD | LYS | B | 299 | 27.708 | 80.363 | 66.098 | 1.00 | 20.84 | B | C |
| ATOM | 1543 | CE | LYS | B | 299 | 28.532 | 81.279 | 65.223 | 1.00 | 19.45 | B | C |
| ATOM | 1544 | NZ | LYS | B | 299 | 28.730 | 82.594 | 65.874 | 1.00 | 19.33 | B | N |
| ATOM | 1545 | C | LYS | B | 299 | 30.309 | 76.383 | 65.421 | 1.00 | 17.05 | B | C |
| ATOM | 1546 | O | LYS | B | 299 | 31.396 | 76.641 | 64.923 | 1.00 | 16.46 | B | O |
| ATOM | 1547 | N | VAL | B | 300 | 29.788 | 75.162 | 65.401 | 1.00 | 15.33 | B | N |
| ATOM | 1548 | CA | VAL | B | 300 | 30.505 | 74.066 | 64.762 | 1.00 | 13.57 | B | C |
| ATOM | 1549 | CB | VAL | B | 300 | 30.903 | 72.981 | 65.791 | 1.00 | 11.25 | B | C |
| ATOM | 1550 | CG1 | VAL | B | 300 | 31.652 | 71.854 | 65.102 | 1.00 | 8.15 | B | C |
| ATOM | 1551 | CG2 | VAL | B | 300 | 31.766 | 73.595 | 66.885 | 1.00 | 12.17 | B | C |
| ATOM | 1552 | C | VAL | B | 300 | 29.681 | 73.411 | 63.657 | 1.00 | 15.16 | B | C |
| ATOM | 1553 | O | VAL | B | 300 | 28.502 | 73.099 | 63.858 | 1.00 | 14.26 | B | O |
| ATOM | 1554 | N | ASP | B | 301 | 30.300 | 73.232 | 62.485 | 1.00 | 14.75 | B | N |
| ATOM | 1555 | CA | ASP | B | 301 | 29.650 | 72.576 | 61.347 | 1.00 | 14.34 | B | C |
| ATOM | 1556 | CB | ASP | B | 301 | 30.358 | 72.929 | 60.035 | 1.00 | 15.89 | B | C |
| ATOM | 1557 | CG | ASP | B | 301 | 29.467 | 72.743 | 58.816 | 1.00 | 16.65 | B | C |
| ATOM | 1558 | OD1 | ASP | B | 301 | 29.757 | 73.373 | 57.779 | 1.00 | 18.36 | B | O |
| ATOM | 1559 | OD2 | ASP | B | 301 | 28.483 | 71.971 | 58.890 | 1.00 | 15.67 | B | O |
| ATOM | 1560 | C | ASP | B | 301 | 29.847 | 71.109 | 61.668 | 1.00 | 12.87 | B | C |
| ATOM | 1561 | O | ASP | B | 301 | 30.877 | 70.521 | 61.353 | 1.00 | 11.57 | B | O |
| ATOM | 1562 | N | THR | B | 302 | 28.847 | 70.535 | 62.317 | 1.00 | 13.27 | B | N |
| ATOM | 1563 | CA | THR | B | 302 | 28.896 | 69.160 | 62.778 | 1.00 | 13.66 | B | C |
| ATOM | 1564 | CB | THR | B | 302 | 27.834 | 68.958 | 63.866 | 1.00 | 12.63 | B | C |
| ATOM | 1565 | OG1 | THR | B | 302 | 26.621 | 69.609 | 63.452 | 1.00 | 13.10 | B | O |
| ATOM | 1566 | CG2 | THR | B | 302 | 28.305 | 69.569 | 65.193 | 1.00 | 8.23 | B | C |
| ATOM | 1567 | C | THR | B | 302 | 28.710 | 68.100 | 61.705 | 1.00 | 16.11 | B | C |
| ATOM | 1568 | O | THR | B | 302 | 28.861 | 66.908 | 61.967 | 1.00 | 16.93 | B | O |
| ATOM | 1569 | N | HIS | B | 303 | 28.388 | 68.525 | 60.495 | 1.00 | 16.93 | B | N |
| ATOM | 1570 | CA | HIS | B | 303 | 28.166 | 67.574 | 59.417 | 1.00 | 17.73 | B | C |
| ATOM | 1571 | CB | HIS | B | 303 | 26.690 | 67.155 | 59.426 | 1.00 | 18.03 | B | C |
| ATOM | 1572 | CG | HIS | B | 303 | 26.201 | 66.578 | 58.137 | 1.00 | 20.35 | B | C |
| ATOM | 1573 | CD2 | HIS | B | 303 | 26.721 | 65.622 | 57.330 | 1.00 | 20.03 | B | C |
| ATOM | 1574 | ND1 | HIS | B | 303 | 25.000 | 66.949 | 57.569 | 1.00 | 19.99 | B | N |
| ATOM | 1575 | CE1 | HIS | B | 303 | 24.800 | 66.244 | 56.471 | 1.00 | 20.00 | B | C |
| ATOM | 1576 | NE2 | HIS | B | 303 | 25.829 | 65.434 | 56.303 | 1.00 | 19.22 | B | N |
| ATOM | 1577 | C | HIS | B | 303 | 28.558 | 68.229 | 58.101 | 1.00 | 17.21 | B | C |
| ATOM | 1578 | O | HIS | B | 303 | 27.788 | 68.991 | 57.525 | 1.00 | 16.74 | B | O |
| ATOM | 1579 | N | ILE | B | 304 | 29.780 | 67.946 | 57.656 | 1.00 | 17.34 | B | N |
| ATOM | 1580 | CA | ILE | B | 304 | 30.304 | 68.500 | 56.415 | 1.00 | 17.35 | B | C |
| ATOM | 1581 | CB | ILE | B | 304 | 30.991 | 69.871 | 56.656 | 1.00 | 15.91 | B | C |
| ATOM | 1582 | CG2 | ILE | B | 304 | 31.952 | 69.775 | 57.812 | 1.00 | 14.66 | B | C |
| ATOM | 1583 | CG1 | ILE | B | 304 | 31.739 | 70.312 | 55.400 | 1.00 | 17.13 | B | C |
| ATOM | 1584 | CD1 | ILE | B | 304 | 31.903 | 71.809 | 55.261 | 1.00 | 17.57 | B | C |
| ATOM | 1585 | C | ILE | B | 304 | 31.312 | 67.538 | 55.793 | 1.00 | 18.26 | B | C |
| ATOM | 1586 | O | ILE | B | 304 | 32.086 | 66.895 | 56.504 | 1.00 | 17.61 | B | O |
| ATOM | 1587 | N | HIS | B | 305 | 31.293 | 67.445 | 54.460 | 1.00 | 18.14 | B | N |
| ATOM | 1588 | CA | HIS | B | 305 | 32.197 | 66.560 | 53.719 | 1.00 | 16.46 | B | C |
| ATOM | 1589 | CB | HIS | B | 305 | 31.416 | 65.818 | 52.626 | 1.00 | 13.83 | B | C |
| ATOM | 1590 | CG | HIS | B | 305 | 30.196 | 65.109 | 53.132 | 1.00 | 11.02 | B | C |
| ATOM | 1591 | CD2 | HIS | B | 305 | 28.969 | 65.573 | 53.472 | 1.00 | 13.12 | B | C |
| ATOM | 1592 | ND1 | HIS | B | 305 | 30.159 | 63.747 | 53.348 | 1.00 | 11.64 | B | N |
| ATOM | 1593 | CE1 | HIS | B | 305 | 28.966 | 63.404 | 53.801 | 1.00 | 10.29 | B | C |
| ATOM | 1594 | NE2 | HIS | B | 305 | 28.225 | 64.492 | 53.885 | 1.00 | 7.06 | B | N |
| ATOM | 1595 | C | HIS | B | 305 | 33.362 | 67.348 | 53.114 | 1.00 | 15.06 | B | C |
| ATOM | 1596 | O | HIS | B | 305 | 33.160 | 68.361 | 52.445 | 1.00 | 15.89 | B | O |
| ATOM | 1597 | N | ALA | B | 306 | 34.580 | 66.878 | 53.371 | 1.00 | 14.82 | B | N |
| ATOM | 1598 | CA | ALA | B | 306 | 35.798 | 67.524 | 52.894 | 1.00 | 15.75 | B | C |
| ATOM | 1599 | CB | ALA | B | 306 | 37.016 | 66.659 | 53.238 | 1.00 | 14.80 | B | C |
| ATOM | 1600 | C | ALA | B | 306 | 35.786 | 67.829 | 51.398 | 1.00 | 16.49 | B | C |
| ATOM | 1601 | O | ALA | B | 306 | 36.192 | 68.908 | 50.981 | 1.00 | 18.00 | B | O |
| ATOM | 1602 | N | ALA | B | 307 | 35.317 | 66.877 | 50.598 | 1.00 | 17.81 | B | N |
| ATOM | 1603 | CA | ALA | B | 307 | 35.267 | 67.037 | 49.147 | 1.00 | 16.71 | B | C |
| ATOM | 1604 | CB | ALA | B | 307 | 34.744 | 65.770 | 48.510 | 1.00 | 14.14 | B | C |
| ATOM | 1605 | C | ALA | B | 307 | 34.426 | 68.220 | 48.687 | 1.00 | 18.69 | B | C |
| ATOM | 1606 | O | ALA | B | 307 | 34.524 | 68.631 | 47.530 | 1.00 | 21.96 | B | O |
| ATOM | 1607 | N | ALA | B | 308 | 33.606 | 68.774 | 49.578 | 1.00 | 18.46 | B | N |
| ATOM | 1608 | CA | ALA | B | 308 | 32.752 | 69.901 | 49.218 | 1.00 | 17.22 | B | C |
| ATOM | 1609 | CB | ALA | B | 308 | 31.329 | 69.426 | 49.049 | 1.00 | 16.89 | B | C |
| ATOM | 1610 | C | ALA | B | 308 | 32.792 | 71.039 | 50.226 | 1.00 | 18.43 | B | C |
| ATOM | 1611 | O | ALA | B | 308 | 31.917 | 71.902 | 50.221 | 1.00 | 18.05 | B | O |
| ATOM | 1612 | N | CYS | B | 309 | 33.815 | 71.063 | 51.073 | 1.00 | 19.81 | B | N |
| ATOM | 1613 | CA | CYS | B | 309 | 33.928 | 72.102 | 52.093 | 1.00 | 22.28 | B | C |
| ATOM | 1614 | CB | CYS | B | 309 | 34.935 | 71.674 | 53.178 | 1.00 | 22.48 | B | C |
| ATOM | 1615 | SG | CYS | B | 309 | 36.678 | 71.577 | 52.685 | 1.00 | 26.64 | B | S |
| ATOM | 1616 | C | CYS | B | 309 | 34.285 | 73.494 | 51.570 | 1.00 | 22.41 | B | C |
| ATOM | 1617 | O | CYS | B | 309 | 34.223 | 74.477 | 52.309 | 1.00 | 22.08 | B | O |
| ATOM | 1618 | N | MET | B | 310 | 34.652 | 73.587 | 50.297 | 1.00 | 23.97 | B | N |
| ATOM | 1619 | CA | MET | B | 310 | 35.010 | 74.879 | 49.704 | 1.00 | 22.79 | B | C |
| ATOM | 1620 | CB | MET | B | 310 | 36.237 | 74.718 | 48.797 | 1.00 | 20.54 | B | C |
| ATOM | 1621 | CG | MET | B | 310 | 35.948 | 74.041 | 47.463 | 1.00 | 15.90 | B | C |
| ATOM | 1622 | SD | MET | B | 310 | 35.584 | 72.289 | 47.597 | 1.00 | 18.14 | B | S |
| ATOM | 1623 | CE | MET | B | 310 | 37.009 | 71.680 | 48.490 | 1.00 | 11.58 | B | C |
| ATOM | 1624 | C | MET | B | 310 | 33.849 | 75.470 | 48.898 | 1.00 | 23.51 | B | C |
| ATOM | 1625 | O | MET | B | 310 | 32.965 | 74.746 | 48.438 | 1.00 | 22.13 | B | O |
| ATOM | 1626 | N | ASN | B | 311 | 33.843 | 76.790 | 48.747 | 1.00 | 24.50 | B | N |
| ATOM | 1627 | CA | ASN | B | 311 | 32.799 | 77.446 | 47.970 | 1.00 | 26.32 | B | C |
| ATOM | 1628 | CB | ASN | B | 311 | 32.778 | 78.954 | 48.243 | 1.00 | 30.23 | B | C |
| ATOM | 1629 | CG | ASN | B | 311 | 31.685 | 79.673 | 47.459 | 1.00 | 37.16 | B | C |
| ATOM | 1630 | OD1 | ASN | B | 311 | 30.498 | 79.334 | 47.556 | 1.00 | 41.40 | B | O |
| ATOM | 1631 | ND2 | ASN | B | 311 | 32.080 | 80.671 | 46.676 | 1.00 | 39.84 | B | N |
| ATOM | 1632 | C | ASN | B | 311 | 33.109 | 77.199 | 46.499 | 1.00 | 24.97 | B | C |
| ATOM | 1633 | O | ASN | B | 311 | 34.271 | 77.039 | 46.122 | 1.00 | 23.19 | B | O |
| ATOM | 1634 | N | GLN | B | 312 | 32.076 | 77.158 | 45.668 | 1.00 | 25.53 | B | N |
| ATOM | 1635 | CA | GLN | B | 312 | 32.290 | 76.930 | 44.252 | 1.00 | 24.74 | B | C |
| ATOM | 1636 | CB | GLN | B | 312 | 30.949 | 76.860 | 43.525 | 1.00 | 23.79 | B | C |
| ATOM | 1637 | CG | GLN | B | 312 | 30.120 | 78.118 | 43.613 | 1.00 | 23.25 | B | C |
| ATOM | 1638 | CD | GLN | B | 312 | 28.836 | 77.998 | 42.816 | 1.00 | 22.20 | B | C |
| ATOM | 1639 | OE1 | GLN | B | 312 | 28.687 | 77.079 | 42.008 | 1.00 | 22.84 | B | O |
| ATOM | 1640 | NE2 | GLN | B | 312 | 27.901 | 78.920 | 43.042 | 1.00 | 20.21 | B | N |
| ATOM | 1641 | C | GLN | B | 312 | 33.186 | 78.022 | 43.651 | 1.00 | 24.21 | B | C |
| ATOM | 1642 | O | GLN | B | 312 | 33.980 | 77.748 | 42.756 | 1.00 | 24.22 | B | O |
| ATOM | 1643 | N | LYS | B | 313 | 33.076 | 79.249 | 44.155 | 1.00 | 22.93 | B | N |
| ATOM | 1644 | CA | LYS | B | 313 | 33.898 | 80.350 | 43.657 | 1.00 | 21.88 | B | C |
| ATOM | 1645 | CB | LYS | B | 313 | 33.353 | 81.693 | 44.144 | 1.00 | 24.06 | B | C |
| ATOM | 1646 | CG | LYS | B | 313 | 32.298 | 82.297 | 43.224 | 1.00 | 27.44 | B | C |
| ATOM | 1647 | CD | LYS | B | 313 | 32.037 | 83.756 | 43.552 | 1.00 | 31.45 | B | C |
| ATOM | 1648 | CE | LYS | B | 313 | 31.435 | 83.911 | 44.937 | 1.00 | 35.26 | B | C |
| ATOM | 1649 | NZ | LYS | B | 313 | 31.507 | 85.322 | 45.414 | 1.00 | 38.92 | B | N |
| ATOM | 1650 | C | LYS | B | 313 | 35.340 | 80.187 | 44.118 | 1.00 | 22.19 | B | C |
| ATOM | 1651 | O | LYS | B | 313 | 36.277 | 80.678 | 43.481 | 1.00 | 20.82 | B | O |
| ATOM | 1652 | N | HIS | B | 314 | 35.505 | 79.498 | 45.241 | 1.00 | 21.96 | B | N |
| ATOM | 1653 | CA | HIS | B | 314 | 36.820 | 79.229 | 45.808 | 1.00 | 20.74 | B | C |
| ATOM | 1654 | CB | HIS | B | 314 | 36.654 | 78.691 | 47.239 | 1.00 | 23.49 | B | C |
| ATOM | 1655 | CG | HIS | B | 314 | 37.945 | 78.376 | 47.936 | 1.00 | 24.66 | B | C |
| ATOM | 1656 | CD2 | HIS | B | 314 | 38.187 | 77.821 | 49.148 | 1.00 | 25.37 | B | C |
| ATOM | 1657 | ND1 | HIS | B | 314 | 39.181 | 78.634 | 47.381 | 1.00 | 25.94 | B | N |
| ATOM | 1658 | CE1 | HIS | B | 314 | 40.127 | 78.252 | 48.221 | 1.00 | 25.61 | B | C |
| ATOM | 1659 | NE2 | HIS | B | 314 | 39.551 | 77.756 | 49.301 | 1.00 | 25.43 | B | N |
| ATOM | 1660 | C | HIS | B | 314 | 37.492 | 78.187 | 44.904 | 1.00 | 20.54 | B | C |
| ATOM | 1661 | O | HIS | B | 314 | 38.647 | 78.342 | 44.507 | 1.00 | 19.60 | B | O |
| ATOM | 1662 | N | LEU | B | 315 | 36.758 | 77.129 | 44.570 | 1.00 | 19.08 | B | N |
| ATOM | 1663 | CA | LEU | B | 315 | 37.287 | 76.092 | 43.701 | 1.00 | 20.04 | B | C |
| ATOM | 1664 | CB | LEU | B | 315 | 36.273 | 74.953 | 43.549 | 1.00 | 19.43 | B | C |
| ATOM | 1665 | CG | LEU | B | 315 | 36.607 | 73.945 | 42.444 | 1.00 | 18.59 | B | C |
| ATOM | 1666 | CD1 | LEU | B | 315 | 37.901 | 73.213 | 42.797 | 1.00 | 18.93 | B | C |
| ATOM | 1667 | CD2 | LEU | B | 315 | 35.454 | 72.964 | 42.270 | 1.00 | 17.98 | B | C |
| ATOM | 1668 | C | LEU | B | 315 | 37.620 | 76.671 | 42.321 | 1.00 | 21.12 | B | C |
| ATOM | 1669 | O | LEU | B | 315 | 38.675 | 76.379 | 41.752 | 1.00 | 20.78 | B | O |
| ATOM | 1670 | N | LEU | B | 316 | 36.719 | 77.491 | 41.786 | 1.00 | 21.94 | B | N |
| ATOM | 1671 | CA | LEU | B | 316 | 36.931 | 78.105 | 40.481 | 1.00 | 22.26 | B | C |
| ATOM | 1672 | CB | LEU | B | 316 | 35.747 | 79.002 | 40.123 | 1.00 | 21.99 | B | C |
| ATOM | 1673 | CG | LEU | B | 316 | 35.829 | 79.692 | 38.756 | 1.00 | 22.19 | B | C |
| ATOM | 1674 | CD1 | LEU | B | 316 | 35.732 | 78.650 | 37.653 | 1.00 | 20.59 | B | C |
| ATOM | 1675 | CD2 | LEU | B | 316 | 34.707 | 80.706 | 38.621 | 1.00 | 20.71 | B | C |
| ATOM | 1676 | C | LEU | B | 316 | 38.213 | 78.929 | 40.496 | 1.00 | 23.88 | B | C |
| ATOM | 1677 | O | LEU | B | 316 | 39.036 | 78.860 | 39.584 | 1.00 | 24.41 | B | O |
| ATOM | 1678 | N | ARG | B | 317 | 38.373 | 79.712 | 41.550 | 1.00 | 25.52 | B | N |
| ATOM | 1679 | CA | ARG | B | 317 | 39.545 | 80.555 | 41.724 | 1.00 | 25.45 | B | C |
| ATOM | 1680 | CB | ARG | B | 317 | 39.419 | 81.306 | 43.051 | 1.00 | 28.27 | B | C |
| ATOM | 1681 | CG | ARG | B | 317 | 40.379 | 82.458 | 43.238 | 1.00 | 32.50 | B | C |
| ATOM | 1682 | CD | ARG | B | 317 | 39.776 | 83.522 | 44.159 | 1.00 | 35.57 | B | C |
| ATOM | 1683 | NE | ARG | B | 317 | 39.345 | 82.979 | 45.450 | 1.00 | 37.42 | B | N |
| ATOM | 1684 | CZ | ARG | B | 317 | 38.101 | 83.055 | 45.915 | 1.00 | 37.55 | B | C |
| ATOM | 1685 | NH1 | ARG | B | 317 | 37.159 | 83.651 | 45.193 | 1.00 | 37.91 | B | N |
| ATOM | 1686 | NH2 | ARG | B | 317 | 37.798 | 82.545 | 47.102 | 1.00 | 37.73 | B | N |
| ATOM | 1687 | C | ARG | B | 317 | 40.828 | 79.724 | 41.719 | 1.00 | 24.41 | B | C |
| ATOM | 1688 | O | ARG | B | 317 | 41.797 | 80.065 | 41.049 | 1.00 | 22.21 | B | O |
| ATOM | 1689 | N | PHE | B | 318 | 40.825 | 78.627 | 42.472 | 1.00 | 23.67 | B | N |
| ATOM | 1690 | CA | PHE | B | 318 | 41.997 | 77.766 | 42.572 | 1.00 | 22.23 | B | C |
| ATOM | 1691 | CB | PHE | B | 318 | 41.805 | 76.718 | 43.672 | 1.00 | 21.12 | B | C |
| ATOM | 1692 | CG | PHE | B | 318 | 42.998 | 75.823 | 43.857 | 1.00 | 22.31 | B | C |
| ATOM | 1693 | CD1 | PHE | B | 318 | 44.022 | 76.178 | 44.732 | 1.00 | 21.48 | B | C |
| ATOM | 1694 | CD2 | PHE | B | 318 | 43.124 | 74.643 | 43.127 | 1.00 | 22.07 | B | C |
| ATOM | 1695 | CE1 | PHE | B | 318 | 45.156 | 75.374 | 44.875 | 1.00 | 20.42 | B | C |
| ATOM | 1696 | CE2 | PHE | B | 318 | 44.255 | 73.833 | 43.263 | 1.00 | 19.67 | B | C |
| ATOM | 1697 | CZ | PHE | B | 318 | 45.273 | 74.199 | 44.138 | 1.00 | 19.40 | B | C |
| ATOM | 1698 | C | PHE | B | 318 | 42.342 | 77.054 | 41.272 | 1.00 | 22.10 | B | C |
| ATOM | 1699 | O | PHE | B | 318 | 43.516 | 76.832 | 40.969 | 1.00 | 21.03 | B | O |
| ATOM | 1700 | N | ILE | B | 319 | 41.325 | 76.674 | 40.509 | 1.00 | 22.08 | B | N |
| ATOM | 1701 | CA | ILE | B | 319 | 41.583 | 75.992 | 39.254 | 1.00 | 21.13 | B | C |
| ATOM | 1702 | CB | ILE | B | 319 | 40.274 | 75.585 | 38.565 | 1.00 | 19.74 | B | C |
| ATOM | 1703 | CG2 | ILE | B | 319 | 40.536 | 75.224 | 37.110 | 1.00 | 18.04 | B | C |
| ATOM | 1704 | CG1 | ILE | B | 319 | 39.662 | 74.398 | 39.302 | 1.00 | 17.44 | B | C |
| ATOM | 1705 | CD1 | ILE | B | 319 | 38.276 | 74.064 | 38.847 | 1.00 | 19.72 | B | C |
| ATOM | 1706 | C | ILE | B | 319 | 42.387 | 76.910 | 38.334 | 1.00 | 23.03 | B | C |
| ATOM | 1707 | O | ILE | B | 319 | 43.395 | 76.499 | 37.755 | 1.00 | 22.65 | B | O |
| ATOM | 1708 | N | LYS | B | 320 | 41.950 | 78.160 | 38.218 | 1.00 | 23.26 | B | N |
| ATOM | 1709 | CA | LYS | B | 320 | 42.631 | 79.116 | 37.361 | 1.00 | 25.01 | B | C |
| ATOM | 1710 | CB | LYS | B | 320 | 41.842 | 80.420 | 37.313 | 1.00 | 23.96 | B | C |
| ATOM | 1711 | CG | LYS | B | 320 | 40.431 | 80.236 | 36.782 | 1.00 | 23.49 | B | C |
| ATOM | 1712 | CD | LYS | B | 320 | 39.801 | 81.560 | 36.411 | 1.00 | 22.44 | B | C |
| ATOM | 1713 | CE | LYS | B | 320 | 38.493 | 81.351 | 35.674 | 1.00 | 23.70 | B | C |
| ATOM | 1714 | NZ | LYS | B | 320 | 37.613 | 82.546 | 35.787 | 1.00 | 26.06 | B | N |
| ATOM | 1715 | C | LYS | B | 320 | 44.061 | 79.380 | 37.819 | 1.00 | 26.68 | B | C |
| ATOM | 1716 | O | LYS | B | 320 | 44.975 | 79.478 | 37.001 | 1.00 | 27.60 | B | O |
| ATOM | 1717 | N | LYS | B | 321 | 44.256 | 79.488 | 39.127 | 1.00 | 27.60 | B | N |
| ATOM | 1718 | CA | LYS | B | 321 | 45.584 | 79.734 | 39.673 | 1.00 | 28.69 | B | C |
| ATOM | 1719 | CB | LYS | B | 321 | 45.499 | 79.991 | 41.183 | 1.00 | 31.26 | B | C |
| ATOM | 1720 | CG | LYS | B | 321 | 46.751 | 80.615 | 41.783 | 1.00 | 33.71 | B | C |
| ATOM | 1721 | CD | LYS | B | 321 | 47.054 | 81.965 | 41.140 | 1.00 | 39.13 | B | C |
| ATOM | 1722 | CE | LYS | B | 321 | 48.320 | 82.603 | 41.711 | 1.00 | 40.05 | B | C |
| ATOM | 1723 | NZ | LYS | B | 321 | 49.298 | 81.587 | 42.196 | 1.00 | 42.99 | B | N |
| ATOM | 1724 | C | LYS | B | 321 | 46.511 | 78.553 | 39.409 | 1.00 | 28.79 | B | C |
| ATOM | 1725 | O | LYS | B | 321 | 47.688 | 78.735 | 39.111 | 1.00 | 29.31 | B | O |
| ATOM | 1726 | N | SER | B | 322 | 45.980 | 77.342 | 39.522 | 1.00 | 28.43 | B | N |
| ATOM | 1727 | CA | SER | B | 322 | 46.778 | 76.146 | 39.298 | 1.00 | 28.39 | B | C |
| ATOM | 1728 | CB | SER | B | 322 | 45.948 | 74.891 | 39.594 | 1.00 | 25.77 | B | C |
| ATOM | 1729 | OG | SER | B | 322 | 44.973 | 74.666 | 38.592 | 1.00 | 24.49 | B | O |
| ATOM | 1730 | C | SER | B | 322 | 47.298 | 76.100 | 37.862 | 1.00 | 30.30 | B | C |
| ATOM | 1731 | O | SER | B | 322 | 48.388 | 75.593 | 37.600 | 1.00 | 28.61 | B | O |
| ATOM | 1732 | N | TYR | B | 323 | 46.513 | 76.637 | 36.932 | 1.00 | 32.25 | B | N |
| ATOM | 1733 | CA | TYR | B | 323 | 46.904 | 76.648 | 35.529 | 1.00 | 33.92 | B | C |
| ATOM | 1734 | CB | TYR | B | 323 | 45.695 | 76.934 | 34.644 | 1.00 | 34.95 | B | C |
| ATOM | 1735 | CG | TYR | B | 323 | 46.032 | 76.991 | 33.175 | 1.00 | 36.49 | B | C |
| ATOM | 1736 | CD1 | TYR | B | 323 | 46.325 | 78.205 | 32.557 | 1.00 | 38.09 | B | C |
| ATOM | 1737 | CE1 | TYR | B | 323 | 46.636 | 78.270 | 31.206 | 1.00 | 38.81 | B | C |
| ATOM | 1738 | CD2 | TYR | B | 323 | 46.059 | 75.833 | 32.400 | 1.00 | 37.43 | B | C |
| ATOM | 1739 | CE2 | TYR | B | 323 | 46.368 | 75.883 | 31.046 | 1.00 | 39.60 | B | C |
| ATOM | 1740 | CZ | TYR | B | 323 | 46.655 | 77.106 | 30.455 | 1.00 | 40.82 | B | C |
| ATOM | 1741 | OH | TYR | B | 323 | 46.957 | 77.171 | 29.112 | 1.00 | 44.58 | B | O |
| ATOM | 1742 | C | TYR | B | 323 | 47.977 | 77.698 | 35.275 | 1.00 | 34.32 | B | C |
| ATOM | 1743 | O | TYR | B | 323 | 48.924 | 77.473 | 34.524 | 1.00 | 33.74 | B | O |
| ATOM | 1744 | N | GLN | B | 324 | 47.818 | 78.853 | 35.904 | 1.00 | 35.12 | B | N |
| ATOM | 1745 | CA | GLN | B | 324 | 48.772 | 79.934 | 35.745 | 1.00 | 35.95 | B | C |
| ATOM | 1746 | CB | GLN | B | 324 | 48.312 | 81.158 | 36.543 | 1.00 | 38.25 | B | C |
| ATOM | 1747 | CG | GLN | B | 324 | 49.392 | 82.199 | 36.787 | 1.00 | 42.22 | B | C |
| ATOM | 1748 | CD | GLN | B | 324 | 49.127 | 83.041 | 38.029 | 1.00 | 45.20 | B | C |
| ATOM | 1749 | OE1 | GLN | B | 324 | 47.998 | 83.479 | 38.273 | 1.00 | 45.72 | B | O |
| ATOM | 1750 | NE2 | GLN | B | 324 | 50.173 | 83.269 | 38.821 | 1.00 | 45.07 | B | N |
| ATOM | 1751 | C | GLN | B | 324 | 50.163 | 79.511 | 36.206 | 1.00 | 35.38 | B | C |
| ATOM | 1752 | O | GLN | B | 324 | 51.167 | 79.943 | 35.641 | 1.00 | 35.27 | B | O |
| ATOM | 1753 | N | VAL | B | 325 | 50.228 | 78.653 | 37.217 | 1.00 | 33.62 | B | N |
| ATOM | 1754 | CA | VAL | B | 325 | 51.526 | 78.230 | 37.732 | 1.00 | 32.29 | B | C |
| ATOM | 1755 | CB | VAL | B | 325 | 51.616 | 78.445 | 39.274 | 1.00 | 30.59 | B | C |
| ATOM | 1756 | CG1 | VAL | B | 325 | 50.834 | 79.680 | 39.680 | 1.00 | 28.98 | B | C |
| ATOM | 1757 | CG2 | VAL | B | 325 | 51.100 | 77.226 | 40.005 | 1.00 | 31.76 | B | C |
| ATOM | 1758 | C | VAL | B | 325 | 51.961 | 76.799 | 37.423 | 1.00 | 32.12 | B | C |
| ATOM | 1759 | O | VAL | B | 325 | 53.152 | 76.497 | 37.491 | 1.00 | 32.80 | B | O |
| ATOM | 1760 | N | ASP | B | 326 | 51.023 | 75.921 | 37.080 | 1.00 | 31.93 | B | N |
| ATOM | 1761 | CA | ASP | B | 326 | 51.375 | 74.530 | 36.795 | 1.00 | 30.97 | B | C |
| ATOM | 1762 | CB | ASP | B | 326 | 50.767 | 73.606 | 37.859 | 1.00 | 31.03 | B | C |
| ATOM | 1763 | CG | ASP | B | 326 | 51.524 | 73.647 | 39.179 | 1.00 | 31.33 | B | C |
| ATOM | 1764 | OD1 | ASP | B | 326 | 52.665 | 74.151 | 39.200 | 1.00 | 30.87 | B | O |
| ATOM | 1765 | OD2 | ASP | B | 326 | 50.977 | 73.173 | 40.200 | 1.00 | 31.21 | B | O |
| ATOM | 1766 | C | ASP | B | 326 | 50.928 | 74.047 | 35.424 | 1.00 | 31.51 | B | C |
| ATOM | 1767 | O | ASP | B | 326 | 50.771 | 72.843 | 35.222 | 1.00 | 33.33 | B | O |
| ATOM | 1768 | N | ALA | B | 327 | 50.725 | 74.969 | 34.487 | 1.00 | 31.04 | B | N |
| ATOM | 1769 | CA | ALA | B | 327 | 50.276 | 74.615 | 33.139 | 1.00 | 31.67 | B | C |
| ATOM | 1770 | CB | ALA | B | 327 | 50.282 | 75.852 | 32.250 | 1.00 | 31.80 | B | C |
| ATOM | 1771 | C | ALA | B | 327 | 51.094 | 73.503 | 32.480 | 1.00 | 33.01 | B | C |
| ATOM | 1772 | O | ALA | B | 327 | 50.555 | 72.687 | 31.722 | 1.00 | 31.94 | B | O |
| ATOM | 1773 | N | ASP | B | 328 | 52.390 | 73.464 | 32.774 | 1.00 | 33.26 | B | N |
| ATOM | 1774 | CA | ASP | B | 328 | 53.263 | 72.455 | 32.184 | 1.00 | 35.61 | B | C |
| ATOM | 1775 | CB | ASP | B | 328 | 54.508 | 73.123 | 31.594 | 1.00 | 38.42 | B | C |
| ATOM | 1776 | CG | ASP | B | 328 | 54.165 | 74.200 | 30.573 | 1.00 | 42.26 | B | C |
| ATOM | 1777 | OD1 | ASP | B | 328 | 53.434 | 73.902 | 29.598 | 1.00 | 43.07 | B | O |
| ATOM | 1778 | OD2 | ASP | B | 328 | 54.628 | 75.347 | 30.752 | 1.00 | 44.09 | B | O |
| ATOM | 1779 | C | ASP | B | 328 | 53.688 | 71.344 | 33.139 | 1.00 | 34.17 | B | C |
| ATOM | 1780 | O | ASP | B | 328 | 54.590 | 70.572 | 32.826 | 1.00 | 35.25 | B | O |
| ATOM | 1781 | N | ARG | B | 329 | 53.042 | 71.266 | 34.298 | 1.00 | 32.79 | B | N |
| ATOM | 1782 | CA | ARG | B | 329 | 53.353 | 70.235 | 35.279 | 1.00 | 30.98 | B | C |
| ATOM | 1783 | CB | ARG | B | 329 | 52.850 | 70.656 | 36.667 | 1.00 | 31.23 | B | C |
| ATOM | 1784 | CG | ARG | B | 329 | 53.630 | 70.067 | 37.838 | 1.00 | 32.17 | B | C |
| ATOM | 1785 | CD | ARG | B | 329 | 52.744 | 69.270 | 38.796 | 1.00 | 33.73 | B | C |
| ATOM | 1786 | NE | ARG | B | 329 | 52.343 | 70.059 | 39.959 | 1.00 | 36.11 | B | N |
| ATOM | 1787 | CZ | ARG | B | 329 | 52.275 | 69.604 | 41.209 | 1.00 | 35.68 | B | C |
| ATOM | 1788 | NH1 | ARG | B | 329 | 52.582 | 68.348 | 41.492 | 1.00 | 36.92 | B | N |
| ATOM | 1789 | NH2 | ARG | B | 329 | 51.882 | 70.409 | 42.181 | 1.00 | 34.65 | B | N |
| ATOM | 1790 | C | ARG | B | 329 | 52.652 | 68.950 | 34.860 | 1.00 | 29.44 | B | C |
| ATOM | 1791 | O | ARG | B | 329 | 51.472 | 68.976 | 34.495 | 1.00 | 27.34 | B | O |
| ATOM | 1792 | N | VAL | B | 330 | 53.369 | 67.830 | 34.887 | 1.00 | 28.35 | B | N |
| ATOM | 1793 | CA | VAL | B | 330 | 52.738 | 66.561 | 34.532 | 1.00 | 30.00 | B | C |
| ATOM | 1794 | CB | VAL | B | 330 | 53.763 | 65.435 | 34.354 | 1.00 | 28.36 | B | C |
| ATOM | 1795 | CG1 | VAL | B | 330 | 53.037 | 64.130 | 34.042 | 1.00 | 28.66 | B | C |
| ATOM | 1796 | CG2 | VAL | B | 330 | 54.717 | 65.786 | 33.231 | 1.00 | 25.32 | B | C |
| ATOM | 1797 | C | VAL | B | 330 | 51.824 | 66.239 | 35.702 | 1.00 | 31.00 | B | C |
| ATOM | 1798 | O | VAL | B | 330 | 52.283 | 66.038 | 36.825 | 1.00 | 31.23 | B | O |
| ATOM | 1799 | N | VAL | B | 331 | 50.529 | 66.182 | 35.434 | 1.00 | 33.08 | B | N |
| ATOM | 1800 | CA | VAL | B | 331 | 49.562 | 65.967 | 36.490 | 1.00 | 34.30 | B | C |
| ATOM | 1801 | CB | VAL | B | 331 | 48.772 | 67.280 | 36.694 | 1.00 | 34.25 | B | C |
| ATOM | 1802 | CG1 | VAL | B | 331 | 47.573 | 67.326 | 35.761 | 1.00 | 33.19 | B | C |
| ATOM | 1803 | CG2 | VAL | B | 331 | 48.362 | 67.414 | 38.130 | 1.00 | 38.04 | B | C |
| ATOM | 1804 | C | VAL | B | 331 | 48.599 | 64.804 | 36.274 | 1.00 | 35.09 | B | C |
| ATOM | 1805 | O | VAL | B | 331 | 47.942 | 64.346 | 37.209 | 1.00 | 34.18 | B | O |
| ATOM | 1806 | N | TYR | B | 332 | 48.532 | 64.316 | 35.044 | 1.00 | 36.73 | B | N |
| ATOM | 1807 | CA | TYR | B | 332 | 47.628 | 63.228 | 34.699 | 1.00 | 39.75 | B | C |
| ATOM | 1808 | CB | TYR | B | 332 | 46.514 | 63.787 | 33.814 | 1.00 | 38.67 | B | C |
| ATOM | 1809 | CG | TYR | B | 332 | 45.464 | 62.804 | 33.351 | 1.00 | 38.95 | B | C |
| ATOM | 1810 | CD1 | TYR | B | 332 | 44.353 | 62.519 | 34.142 | 1.00 | 39.71 | B | C |
| ATOM | 1811 | CE1 | TYR | B | 332 | 43.325 | 61.692 | 33.674 | 1.00 | 41.80 | B | C |
| ATOM | 1812 | CD2 | TYR | B | 332 | 45.533 | 62.233 | 32.080 | 1.00 | 39.32 | B | C |
| ATOM | 1813 | CE2 | TYR | B | 332 | 44.513 | 61.405 | 31.600 | 1.00 | 40.14 | B | C |
| ATOM | 1814 | CZ | TYR | B | 332 | 43.411 | 61.142 | 32.399 | 1.00 | 40.94 | B | C |
| ATOM | 1815 | OH | TYR | B | 332 | 42.388 | 60.350 | 31.922 | 1.00 | 42.33 | B | O |
| ATOM | 1816 | C | TYR | B | 332 | 48.396 | 62.133 | 33.973 | 1.00 | 42.15 | B | C |
| ATOM | 1817 | O | TYR | B | 332 | 49.444 | 62.393 | 33.386 | 1.00 | 42.40 | B | O |
| ATOM | 1818 | N | SER | B | 333 | 47.879 | 60.910 | 34.011 | 1.00 | 45.79 | B | N |
| ATOM | 1819 | CA | SER | B | 333 | 48.551 | 59.797 | 33.351 | 1.00 | 48.39 | B | C |
| ATOM | 1820 | CB | SER | B | 333 | 48.972 | 58.752 | 34.388 | 1.00 | 48.56 | B | C |
| ATOM | 1821 | OG | SER | B | 333 | 49.566 | 57.634 | 33.756 | 1.00 | 47.74 | B | O |
| ATOM | 1822 | C | SER | B | 333 | 47.722 | 59.119 | 32.260 | 1.00 | 50.38 | B | C |
| ATOM | 1823 | O | SER | B | 333 | 46.575 | 58.727 | 32.482 | 1.00 | 49.69 | B | O |
| ATOM | 1824 | N | THR | B | 334 | 48.318 | 59.001 | 31.077 | 1.00 | 52.84 | B | N |
| ATOM | 1825 | CA | THR | B | 334 | 47.688 | 58.347 | 29.931 | 1.00 | 56.61 | B | C |
| ATOM | 1826 | CB | THR | B | 334 | 47.184 | 59.371 | 28.877 | 1.00 | 56.06 | B | C |
| ATOM | 1827 | OG1 | THR | B | 334 | 45.754 | 59.310 | 28.809 | 1.00 | 57.15 | B | O |
| ATOM | 1828 | CG2 | THR | B | 334 | 47.755 | 59.065 | 27.490 | 1.00 | 56.18 | B | C |
| ATOM | 1829 | C | THR | B | 334 | 48.751 | 57.441 | 29.312 | 1.00 | 58.93 | B | C |
| ATOM | 1830 | O | THR | B | 334 | 49.941 | 57.774 | 29.325 | 1.00 | 58.84 | B | O |
| ATOM | 1831 | N | LYS | B | 335 | 48.319 | 56.303 | 28.773 | 1.00 | 59.96 | B | N |
| ATOM | 1832 | CA | LYS | B | 335 | 49.234 | 55.329 | 28.181 | 1.00 | 61.21 | B | C |
| ATOM | 1833 | CB | LYS | B | 335 | 48.465 | 54.335 | 27.311 | 1.00 | 60.08 | B | C |
| ATOM | 1834 | CG | LYS | B | 335 | 49.017 | 52.911 | 27.388 | 1.00 | 59.30 | B | C |
| ATOM | 1835 | CD | LYS | B | 335 | 50.474 | 52.819 | 26.931 | 1.00 | 57.82 | B | C |
| ATOM | 1836 | CE | LYS | B | 335 | 51.344 | 52.101 | 27.959 | 1.00 | 56.65 | B | C |
| ATOM | 1837 | NZ | LYS | B | 335 | 52.247 | 51.078 | 27.345 | 1.00 | 55.09 | B | N |
| ATOM | 1838 | C | LYS | B | 335 | 50.401 | 55.885 | 27.376 | 1.00 | 62.11 | B | C |
| ATOM | 1839 | O | LYS | B | 335 | 51.533 | 55.936 | 27.865 | 1.00 | 63.11 | B | O |
| ATOM | 1840 | N | GLU | B | 336 | 50.132 | 56.287 | 26.138 | 1.00 | 62.41 | B | N |
| ATOM | 1841 | CA | GLU | B | 336 | 51.185 | 56.811 | 25.273 | 1.00 | 63.26 | B | C |
| ATOM | 1842 | CB | GLU | B | 336 | 50.622 | 57.130 | 23.883 | 1.00 | 65.96 | B | C |
| ATOM | 1843 | CG | GLU | B | 336 | 51.331 | 56.406 | 22.729 | 1.00 | 69.00 | B | C |
| ATOM | 1844 | CD | GLU | B | 336 | 52.445 | 55.470 | 23.196 | 1.00 | 70.84 | B | C |
| ATOM | 1845 | OE1 | GLU | B | 336 | 53.584 | 55.950 | 23.405 | 1.00 | 71.85 | B | O |
| ATOM | 1846 | OE2 | GLU | B | 336 | 52.179 | 54.255 | 23.352 | 1.00 | 70.77 | B | O |
| ATOM | 1847 | C | GLU | B | 336 | 51.886 | 58.041 | 25.842 | 1.00 | 62.01 | B | C |
| ATOM | 1848 | O | GLU | B | 336 | 53.008 | 58.364 | 25.441 | 1.00 | 61.53 | B | O |
| ATOM | 1849 | N | LYS | B | 337 | 51.231 | 58.724 | 26.779 | 1.00 | 60.26 | B | N |
| ATOM | 1850 | CA | LYS | B | 337 | 51.822 | 59.910 | 27.385 | 1.00 | 57.29 | B | C |
| ATOM | 1851 | CB | LYS | B | 337 | 51.994 | 60.999 | 26.319 | 1.00 | 56.83 | B | C |
| ATOM | 1852 | CG | LYS | B | 337 | 52.522 | 62.325 | 26.840 | 1.00 | 56.58 | B | C |
| ATOM | 1853 | CD | LYS | B | 337 | 52.385 | 63.423 | 25.790 | 1.00 | 57.11 | B | C |
| ATOM | 1854 | CE | LYS | B | 337 | 52.702 | 64.797 | 26.377 | 1.00 | 58.33 | B | C |
| ATOM | 1855 | NZ | LYS | B | 337 | 53.876 | 65.468 | 25.735 | 1.00 | 58.21 | B | N |
| ATOM | 1856 | C | LYS | B | 337 | 51.009 | 60.461 | 28.554 | 1.00 | 55.59 | B | C |
| ATOM | 1857 | O | LYS | B | 337 | 49.786 | 60.575 | 28.478 | 1.00 | 55.22 | B | O |
| ATOM | 1858 | N | ASN | B | 338 | 51.698 | 60.781 | 29.645 | 1.00 | 52.89 | B | N |
| ATOM | 1859 | CA | ASN | B | 338 | 51.048 | 61.366 | 30.809 | 1.00 | 49.82 | B | C |
| ATOM | 1860 | CB | ASN | B | 338 | 51.948 | 61.253 | 32.041 | 1.00 | 49.51 | B | C |
| ATOM | 1861 | CG | ASN | B | 338 | 52.549 | 59.868 | 32.202 | 1.00 | 48.50 | B | C |
| ATOM | 1862 | OD1 | ASN | B | 338 | 51.829 | 58.871 | 32.299 | 1.00 | 48.32 | B | O |
| ATOM | 1863 | ND2 | ASN | B | 338 | 53.875 | 59.801 | 32.234 | 1.00 | 46.85 | B | N |
| ATOM | 1864 | C | ASN | B | 338 | 50.902 | 62.824 | 30.391 | 1.00 | 47.14 | B | C |
| ATOM | 1865 | O | ASN | B | 338 | 51.794 | 63.364 | 29.740 | 1.00 | 45.84 | B | O |
| ATOM | 1866 | N | LEU | B | 339 | 49.796 | 63.464 | 30.750 | 1.00 | 44.18 | B | N |
| ATOM | 1867 | CA | LEU | B | 339 | 49.582 | 64.848 | 30.339 | 1.00 | 39.60 | B | C |
| ATOM | 1868 | CB | LEU | B | 339 | 48.132 | 65.043 | 29.892 | 1.00 | 39.27 | B | C |
| ATOM | 1869 | CG | LEU | B | 339 | 47.332 | 63.783 | 29.569 | 1.00 | 40.48 | B | C |
| ATOM | 1870 | CD1 | LEU | B | 339 | 45.868 | 64.142 | 29.371 | 1.00 | 39.90 | B | C |
| ATOM | 1871 | CD2 | LEU | B | 339 | 47.900 | 63.131 | 28.321 | 1.00 | 40.50 | B | C |
| ATOM | 1872 | C | LEU | B | 339 | 49.907 | 65.908 | 31.374 | 1.00 | 38.02 | B | C |
| ATOM | 1873 | O | LEU | B | 339 | 49.823 | 65.672 | 32.579 | 1.00 | 37.55 | B | O |
| ATOM | 1874 | N | THR | B | 340 | 50.289 | 67.083 | 30.887 | 1.00 | 34.62 | B | N |
| ATOM | 1875 | CA | THR | B | 340 | 50.564 | 68.206 | 31.764 | 1.00 | 31.92 | B | C |
| ATOM | 1876 | CB | THR | B | 340 | 51.430 | 69.284 | 31.083 | 1.00 | 31.19 | B | C |
| ATOM | 1877 | OG1 | THR | B | 340 | 50.718 | 69.839 | 29.973 | 1.00 | 29.36 | B | O |
| ATOM | 1878 | CG2 | THR | B | 340 | 52.741 | 68.700 | 30.608 | 1.00 | 30.21 | B | C |
| ATOM | 1879 | C | THR | B | 340 | 49.185 | 68.797 | 32.028 | 1.00 | 30.54 | B | C |
| ATOM | 1880 | O | THR | B | 340 | 48.208 | 68.396 | 31.393 | 1.00 | 28.98 | B | O |
| ATOM | 1881 | N | LEU | B | 341 | 49.097 | 69.739 | 32.961 | 1.00 | 30.32 | B | N |
| ATOM | 1882 | CA | LEU | B | 341 | 47.815 | 70.360 | 33.272 | 1.00 | 30.25 | B | C |
| ATOM | 1883 | CB | LEU | B | 341 | 48.003 | 71.478 | 34.308 | 1.00 | 29.87 | B | C |
| ATOM | 1884 | CG | LEU | B | 341 | 46.745 | 72.189 | 34.826 | 1.00 | 28.85 | B | C |
| ATOM | 1885 | CD1 | LEU | B | 341 | 45.763 | 71.170 | 35.381 | 1.00 | 28.30 | B | C |
| ATOM | 1886 | CD2 | LEU | B | 341 | 47.129 | 73.201 | 35.890 | 1.00 | 25.65 | B | C |
| ATOM | 1887 | C | LEU | B | 341 | 47.207 | 70.926 | 31.985 | 1.00 | 30.56 | B | C |
| ATOM | 1888 | O | LEU | B | 341 | 46.035 | 70.686 | 31.674 | 1.00 | 30.04 | B | O |
| ATOM | 1889 | N | LYS | B | 342 | 48.024 | 71.660 | 31.234 | 1.00 | 31.53 | B | N |
| ATOM | 1890 | CA | LYS | B | 342 | 47.592 | 72.268 | 29.980 | 1.00 | 31.06 | B | C |
| ATOM | 1891 | CB | LYS | B | 342 | 48.762 | 72.995 | 29.328 | 1.00 | 32.03 | B | C |
| ATOM | 1892 | CG | LYS | B | 342 | 48.380 | 73.815 | 28.114 | 1.00 | 35.11 | B | C |
| ATOM | 1893 | CD | LYS | B | 342 | 49.586 | 74.577 | 27.568 | 1.00 | 39.73 | B | C |
| ATOM | 1894 | CE | LYS | B | 342 | 49.263 | 76.050 | 27.318 | 1.00 | 42.15 | B | C |
| ATOM | 1895 | NZ | LYS | B | 342 | 50.048 | 76.966 | 28.204 | 1.00 | 43.69 | B | N |
| ATOM | 1896 | C | LYS | B | 342 | 47.034 | 71.237 | 29.014 | 1.00 | 30.28 | B | C |
| ATOM | 1897 | O | LYS | B | 342 | 45.981 | 71.444 | 28.415 | 1.00 | 30.71 | B | O |
| ATOM | 1898 | N | GLN | B | 343 | 47.739 | 70.121 | 28.870 | 1.00 | 30.62 | B | N |
| ATOM | 1899 | CA | GLN | B | 343 | 47.311 | 69.060 | 27.966 | 1.00 | 30.64 | B | C |
| ATOM | 1900 | CB | GLN | B | 343 | 48.370 | 67.965 | 27.886 | 1.00 | 32.19 | B | C |
| ATOM | 1901 | CG | GLN | B | 343 | 49.632 | 68.367 | 27.163 | 1.00 | 33.37 | B | C |
| ATOM | 1902 | CD | GLN | B | 343 | 50.729 | 67.343 | 27.335 | 1.00 | 36.42 | B | C |
| ATOM | 1903 | OE1 | GLN | B | 343 | 50.462 | 66.179 | 27.632 | 1.00 | 40.48 | B | O |
| ATOM | 1904 | NE2 | GLN | B | 343 | 51.971 | 67.769 | 27.154 | 1.00 | 36.35 | B | N |
| ATOM | 1905 | C | GLN | B | 343 | 46.000 | 68.433 | 28.391 | 1.00 | 30.65 | B | C |
| ATOM | 1906 | O | GLN | B | 343 | 45.184 | 68.064 | 27.544 | 1.00 | 31.25 | B | O |
| ATOM | 1907 | N | LEU | B | 344 | 45.806 | 68.292 | 29.701 | 1.00 | 29.75 | B | N |
| ATOM | 1908 | CA | LEU | B | 344 | 44.580 | 67.694 | 30.211 | 1.00 | 29.04 | B | C |
| ATOM | 1909 | CB | LEU | B | 344 | 44.660 | 67.507 | 31.730 | 1.00 | 26.88 | B | C |
| ATOM | 1910 | CG | LEU | B | 344 | 43.380 | 67.007 | 32.406 | 1.00 | 27.29 | B | C |
| ATOM | 1911 | CD1 | LEU | B | 344 | 42.975 | 65.656 | 31.836 | 1.00 | 25.86 | B | C |
| ATOM | 1912 | CD2 | LEU | B | 344 | 43.608 | 66.911 | 33.908 | 1.00 | 27.51 | B | C |
| ATOM | 1913 | C | LEU | B | 344 | 43.393 | 68.578 | 29.849 | 1.00 | 28.78 | B | C |
| ATOM | 1914 | O | LEU | B | 344 | 42.349 | 68.086 | 29.419 | 1.00 | 28.29 | B | O |
| ATOM | 1915 | N | PHE | B | 345 | 43.556 | 69.886 | 30.012 | 1.00 | 30.19 | B | N |
| ATOM | 1916 | CA | PHE | B | 345 | 42.473 | 70.808 | 29.688 | 1.00 | 32.93 | B | C |
| ATOM | 1917 | CB | PHE | B | 345 | 42.816 | 72.223 | 30.168 | 1.00 | 31.67 | B | C |
| ATOM | 1918 | CG | PHE | B | 345 | 42.512 | 72.452 | 31.627 | 1.00 | 30.31 | B | C |
| ATOM | 1919 | CD1 | PHE | B | 345 | 41.202 | 72.400 | 32.095 | 1.00 | 30.45 | B | C |
| ATOM | 1920 | CD2 | PHE | B | 345 | 43.536 | 72.692 | 32.537 | 1.00 | 29.90 | B | C |
| ATOM | 1921 | CE1 | PHE | B | 345 | 40.917 | 72.580 | 33.448 | 1.00 | 28.83 | B | C |
| ATOM | 1922 | CE2 | PHE | B | 345 | 43.261 | 72.875 | 33.895 | 1.00 | 29.89 | B | C |
| ATOM | 1923 | CZ | PHE | B | 345 | 41.946 | 72.817 | 34.349 | 1.00 | 27.72 | B | C |
| ATOM | 1924 | C | PHE | B | 345 | 42.219 | 70.789 | 28.181 | 1.00 | 33.96 | B | C |
| ATOM | 1925 | O | PHE | B | 345 | 41.110 | 71.077 | 27.719 | 1.00 | 34.20 | B | O |
| ATOM | 1926 | N | ASP | B | 346 | 43.254 | 70.439 | 27.423 | 1.00 | 35.94 | B | N |
| ATOM | 1927 | CA | ASP | B | 346 | 43.158 | 70.348 | 25.970 | 1.00 | 36.21 | B | C |
| ATOM | 1928 | CB | ASP | B | 346 | 44.545 | 70.200 | 25.356 | 1.00 | 39.41 | B | C |
| ATOM | 1929 | CG | ASP | B | 346 | 45.151 | 71.524 | 24.976 | 1.00 | 40.80 | B | C |
| ATOM | 1930 | OD1 | ASP | B | 346 | 44.489 | 72.561 | 25.186 | 1.00 | 44.30 | B | O |
| ATOM | 1931 | OD2 | ASP | B | 346 | 46.292 | 71.530 | 24.470 | 1.00 | 45.08 | B | O |
| ATOM | 1932 | C | ASP | B | 346 | 42.323 | 69.127 | 25.617 | 1.00 | 35.62 | B | C |
| ATOM | 1933 | O | ASP | B | 346 | 41.430 | 69.191 | 24.778 | 1.00 | 36.45 | B | O |
| ATOM | 1934 | N | LYS | B | 347 | 42.632 | 68.012 | 26.265 | 1.00 | 35.21 | B | N |
| ATOM | 1935 | CA | LYS | B | 347 | 41.907 | 66.772 | 26.046 | 1.00 | 34.74 | B | C |
| ATOM | 1936 | CB | LYS | B | 347 | 42.519 | 65.654 | 26.896 | 1.00 | 36.70 | B | C |
| ATOM | 1937 | CG | LYS | B | 347 | 41.931 | 64.278 | 26.644 | 1.00 | 39.28 | B | C |
| ATOM | 1938 | CD | LYS | B | 347 | 41.278 | 63.713 | 27.895 | 1.00 | 43.34 | B | C |
| ATOM | 1939 | CE | LYS | B | 347 | 42.204 | 62.752 | 28.617 | 1.00 | 44.66 | B | C |
| ATOM | 1940 | NZ | LYS | B | 347 | 41.769 | 61.338 | 28.465 | 1.00 | 46.16 | B | N |
| ATOM | 1941 | C | LYS | B | 347 | 40.457 | 66.987 | 26.449 | 1.00 | 34.58 | B | C |
| ATOM | 1942 | O | LYS | B | 347 | 39.557 | 66.326 | 25.935 | 1.00 | 35.35 | B | O |
| ATOM | 1943 | N | LEU | B | 348 | 40.237 | 67.917 | 27.376 | 1.00 | 33.10 | B | N |
| ATOM | 1944 | CA | LEU | B | 348 | 38.895 | 68.214 | 27.858 | 1.00 | 33.01 | B | C |
| ATOM | 1945 | CB | LEU | B | 348 | 38.946 | 68.654 | 29.323 | 1.00 | 32.57 | B | C |
| ATOM | 1946 | CG | LEU | B | 348 | 39.342 | 67.576 | 30.336 | 1.00 | 32.38 | B | C |
| ATOM | 1947 | CD1 | LEU | B | 348 | 39.399 | 68.189 | 31.722 | 1.00 | 31.13 | B | C |
| ATOM | 1948 | CD2 | LEU | B | 348 | 38.344 | 66.422 | 30.299 | 1.00 | 31.41 | B | C |
| ATOM | 1949 | C | LEU | B | 348 | 38.232 | 69.294 | 27.019 | 1.00 | 34.06 | B | C |
| ATOM | 1950 | O | LEU | B | 348 | 37.023 | 69.501 | 27.105 | 1.00 | 34.87 | B | O |
| ATOM | 1951 | N | LYS | B | 349 | 39.033 | 69.982 | 26.214 | 1.00 | 35.62 | B | N |
| ATOM | 1952 | CA | LYS | B | 349 | 38.538 | 71.039 | 25.339 | 1.00 | 36.51 | B | C |
| ATOM | 1953 | CB | LYS | B | 349 | 37.375 | 70.496 | 24.486 | 1.00 | 40.16 | B | C |
| ATOM | 1954 | CG | LYS | B | 349 | 36.565 | 71.537 | 23.712 | 1.00 | 45.32 | B | C |
| ATOM | 1955 | CD | LYS | B | 349 | 35.116 | 71.620 | 24.223 | 1.00 | 49.01 | B | C |
| ATOM | 1956 | CE | LYS | B | 349 | 34.599 | 73.060 | 24.241 | 1.00 | 51.69 | B | C |
| ATOM | 1957 | NZ | LYS | B | 349 | 34.729 | 73.742 | 22.910 | 1.00 | 54.14 | B | N |
| ATOM | 1958 | C | LYS | B | 349 | 38.105 | 72.278 | 26.126 | 1.00 | 36.12 | B | C |
| ATOM | 1959 | O | LYS | B | 349 | 37.014 | 72.809 | 25.922 | 1.00 | 36.10 | B | O |
| ATOM | 1960 | N | LEU | B | 350 | 38.958 | 72.743 | 27.034 | 1.00 | 33.99 | B | N |
| ATOM | 1961 | CA | LEU | B | 350 | 38.625 | 73.933 | 27.811 | 1.00 | 32.39 | B | C |
| ATOM | 1962 | CB | LEU | B | 350 | 37.891 | 73.577 | 29.112 | 1.00 | 31.60 | B | C |
| ATOM | 1963 | CG | LEU | B | 350 | 37.244 | 72.212 | 29.340 | 1.00 | 32.90 | B | C |
| ATOM | 1964 | CD1 | LEU | B | 350 | 37.585 | 71.709 | 30.738 | 1.00 | 31.94 | B | C |
| ATOM | 1965 | CD2 | LEU | B | 350 | 35.738 | 72.335 | 29.172 | 1.00 | 32.57 | B | C |
| ATOM | 1966 | C | LEU | B | 350 | 39.837 | 74.751 | 28.186 | 1.00 | 32.40 | B | C |
| ATOM | 1967 | O | LEU | B | 350 | 40.965 | 74.259 | 28.181 | 1.00 | 32.24 | B | O |
| ATOM | 1968 | N | HIS | B | 351 | 39.594 | 76.017 | 28.495 | 1.00 | 32.47 | B | N |
| ATOM | 1969 | CA | HIS | B | 351 | 40.659 | 76.884 | 28.952 | 1.00 | 33.94 | B | C |
| ATOM | 1970 | CB | HIS | B | 351 | 40.909 | 78.052 | 28.006 | 1.00 | 35.41 | B | C |
| ATOM | 1971 | CG | HIS | B | 351 | 42.173 | 78.789 | 28.318 | 1.00 | 38.03 | B | C |
| ATOM | 1972 | CD2 | HIS | B | 351 | 42.470 | 79.670 | 29.303 | 1.00 | 39.22 | B | C |
| ATOM | 1973 | ND1 | HIS | B | 351 | 43.345 | 78.583 | 27.623 | 1.00 | 39.03 | B | N |
| ATOM | 1974 | CE1 | HIS | B | 351 | 44.309 | 79.304 | 28.168 | 1.00 | 40.79 | B | C |
| ATOM | 1975 | NE2 | HIS | B | 351 | 43.804 | 79.972 | 29.189 | 1.00 | 40.55 | B | N |
| ATOM | 1976 | C | HIS | B | 351 | 40.218 | 77.408 | 30.310 | 1.00 | 33.05 | B | C |
| ATOM | 1977 | O | HIS | B | 351 | 39.251 | 78.162 | 30.415 | 1.00 | 32.36 | B | O |
| ATOM | 1978 | N | PRO | B | 352 | 40.916 | 76.992 | 31.374 | 1.00 | 32.92 | B | N |
| ATOM | 1979 | CD | PRO | B | 352 | 42.064 | 76.074 | 31.336 | 1.00 | 32.79 | B | C |
| ATOM | 1980 | CA | PRO | B | 352 | 40.599 | 77.412 | 32.740 | 1.00 | 33.02 | B | C |
| ATOM | 1981 | CB | PRO | B | 352 | 41.890 | 77.135 | 33.520 | 1.00 | 32.92 | B | C |
| ATOM | 1982 | CG | PRO | B | 352 | 42.822 | 76.435 | 32.565 | 1.00 | 31.81 | B | C |
| ATOM | 1983 | C | PRO | B | 352 | 40.152 | 78.864 | 32.873 | 1.00 | 32.88 | B | C |
| ATOM | 1984 | O | PRO | B | 352 | 39.248 | 79.170 | 33.650 | 1.00 | 33.44 | B | O |
| ATOM | 1985 | N | TYR | B | 353 | 40.768 | 79.755 | 32.103 | 1.00 | 32.39 | B | N |
| ATOM | 1986 | CA | TYR | B | 353 | 40.439 | 81.174 | 32.181 | 1.00 | 31.15 | B | C |
| ATOM | 1987 | CB | TYR | B | 353 | 41.519 | 81.995 | 31.474 | 1.00 | 31.78 | B | C |
| ATOM | 1988 | CG | TYR | B | 353 | 42.879 | 81.883 | 32.136 | 1.00 | 34.57 | B | C |
| ATOM | 1989 | CD1 | TYR | B | 353 | 43.027 | 81.241 | 33.371 | 1.00 | 35.28 | B | C |
| ATOM | 1990 | CE1 | TYR | B | 353 | 44.277 | 81.119 | 33.981 | 1.00 | 35.42 | B | C |
| ATOM | 1991 | CD2 | TYR | B | 353 | 44.022 | 82.405 | 31.525 | 1.00 | 34.57 | B | C |
| ATOM | 1992 | CE2 | TYR | B | 353 | 45.282 | 82.288 | 32.127 | 1.00 | 34.21 | B | C |
| ATOM | 1993 | CZ | TYR | B | 353 | 45.401 | 81.644 | 33.353 | 1.00 | 36.60 | B | C |
| ATOM | 1994 | OH | TYR | B | 353 | 46.639 | 81.518 | 33.950 | 1.00 | 36.09 | B | O |
| ATOM | 1995 | C | TYR | B | 353 | 39.058 | 81.558 | 31.664 | 1.00 | 30.03 | B | C |
| ATOM | 1996 | O | TYR | B | 353 | 38.553 | 82.628 | 31.997 | 1.00 | 29.31 | B | O |
| ATOM | 1997 | N | ASP | B | 354 | 38.443 | 80.690 | 30.866 | 1.00 | 28.53 | B | N |
| ATOM | 1998 | CA | ASP | B | 354 | 37.105 | 80.959 | 30.334 | 1.00 | 28.30 | B | C |
| ATOM | 1999 | CB | ASP | B | 354 | 36.922 | 80.319 | 28.954 | 1.00 | 30.35 | B | C |
| ATOM | 2000 | CG | ASP | B | 354 | 37.916 | 80.832 | 27.936 | 1.00 | 32.79 | B | C |
| ATOM | 2001 | OD1 | ASP | B | 354 | 38.303 | 82.016 | 28.028 | 1.00 | 34.22 | B | O |
| ATOM | 2002 | OD2 | ASP | B | 354 | 38.312 | 80.048 | 27.047 | 1.00 | 33.80 | B | O |
| ATOM | 2003 | C | ASP | B | 354 | 36.046 | 80.400 | 31.269 | 1.00 | 26.55 | B | C |
| ATOM | 2004 | O | ASP | B | 354 | 34.854 | 80.674 | 31.108 | 1.00 | 26.52 | B | O |
| ATOM | 2005 | N | LEU | B | 355 | 36.491 | 79.608 | 32.240 | 1.00 | 24.02 | B | N |
| ATOM | 2006 | CA | LEU | B | 355 | 35.585 | 78.998 | 33.195 | 1.00 | 21.79 | B | C |
| ATOM | 2007 | CB | LEU | B | 355 | 36.362 | 78.112 | 34.159 | 1.00 | 19.35 | B | C |
| ATOM | 2008 | CG | LEU | B | 355 | 36.747 | 76.783 | 33.507 | 1.00 | 19.89 | B | C |
| ATOM | 2009 | CD1 | LEU | B | 355 | 37.608 | 75.961 | 34.460 | 1.00 | 19.66 | B | C |
| ATOM | 2010 | CD2 | LEU | B | 355 | 35.482 | 76.020 | 33.118 | 1.00 | 19.57 | B | C |
| ATOM | 2011 | C | LEU | B | 355 | 34.787 | 80.040 | 33.952 | 1.00 | 21.35 | B | C |
| ATOM | 2012 | O | LEU | B | 355 | 35.251 | 81.154 | 34.196 | 1.00 | 21.21 | B | O |
| ATOM | 2013 | N | THR | B | 356 | 33.575 | 79.652 | 34.317 | 1.00 | 20.13 | B | N |
| ATOM | 2014 | CA | THR | B | 356 | 32.637 | 80.508 | 35.018 | 1.00 | 19.90 | B | C |
| ATOM | 2015 | CB | THR | B | 356 | 31.625 | 81.034 | 33.983 | 1.00 | 19.90 | B | C |
| ATOM | 2016 | OG1 | THR | B | 356 | 32.112 | 82.262 | 33.430 | 1.00 | 23.57 | B | O |
| ATOM | 2017 | CG2 | THR | B | 356 | 30.275 | 81.247 | 34.584 | 1.00 | 21.58 | B | C |
| ATOM | 2018 | C | THR | B | 356 | 31.964 | 79.592 | 36.044 | 1.00 | 20.44 | B | C |
| ATOM | 2019 | O | THR | B | 356 | 32.159 | 78.379 | 35.976 | 1.00 | 22.19 | B | O |
| ATOM | 2020 | N | VAL | B | 357 | 31.211 | 80.124 | 37.008 | 1.00 | 19.70 | B | N |
| ATOM | 2021 | CA | VAL | B | 357 | 30.546 | 79.212 | 37.941 | 1.00 | 19.61 | B | C |
| ATOM | 2022 | CB | VAL | B | 357 | 29.895 | 79.937 | 39.181 | 1.00 | 19.36 | B | C |
| ATOM | 2023 | CG1 | VAL | B | 357 | 30.948 | 80.752 | 39.926 | 1.00 | 16.85 | B | C |
| ATOM | 2024 | CG2 | VAL | B | 357 | 28.737 | 80.804 | 38.753 | 1.00 | 19.37 | B | C |
| ATOM | 2025 | C | VAL | B | 357 | 29.471 | 78.468 | 37.135 | 1.00 | 19.28 | B | C |
| ATOM | 2026 | O | VAL | B | 357 | 29.088 | 77.347 | 37.470 | 1.00 | 18.04 | B | O |
| ATOM | 2027 | N | ASP | B | 358 | 29.007 | 79.091 | 36.051 | 1.00 | 19.17 | B | N |
| ATOM | 2028 | CA | ASP | B | 358 | 28.008 | 78.477 | 35.175 | 1.00 | 18.85 | B | C |
| ATOM | 2029 | CB | ASP | B | 358 | 27.563 | 79.455 | 34.087 | 1.00 | 20.47 | B | C |
| ATOM | 2030 | CG | ASP | B | 358 | 26.694 | 80.570 | 34.614 | 1.00 | 21.60 | B | C |
| ATOM | 2031 | OD1 | ASP | B | 358 | 25.996 | 80.368 | 35.633 | 1.00 | 23.74 | B | O |
| ATOM | 2032 | OD2 | ASP | B | 358 | 26.708 | 81.654 | 33.991 | 1.00 | 25.82 | B | O |
| ATOM | 2033 | C | ASP | B | 358 | 28.602 | 77.239 | 34.496 | 1.00 | 17.30 | B | C |
| ATOM | 2034 | O | ASP | B | 358 | 27.979 | 76.181 | 34.463 | 1.00 | 18.15 | B | O |
| ATOM | 2035 | N | SER | B | 359 | 29.802 | 77.384 | 33.939 | 1.00 | 18.06 | B | N |
| ATOM | 2036 | CA | SER | B | 359 | 30.476 | 76.274 | 33.269 | 1.00 | 19.05 | B | C |
| ATOM | 2037 | CB | SER | B | 359 | 31.558 | 76.795 | 32.320 | 1.00 | 17.93 | B | C |
| ATOM | 2038 | OG | SER | B | 359 | 32.252 | 77.891 | 32.879 | 1.00 | 20.68 | B | O |
| ATOM | 2039 | C | SER | B | 359 | 31.087 | 75.305 | 34.282 | 1.00 | 19.03 | B | C |
| ATOM | 2040 | O | SER | B | 359 | 31.222 | 74.113 | 34.004 | 1.00 | 18.85 | B | O |
| ATOM | 2041 | N | LEU | B | 360 | 31.468 | 75.816 | 35.450 | 1.00 | 19.91 | B | N |
| ATOM | 2042 | CA | LEU | B | 360 | 32.018 | 74.964 | 36.503 | 1.00 | 19.52 | B | C |
| ATOM | 2043 | CB | LEU | B | 360 | 32.397 | 75.798 | 37.729 | 1.00 | 18.71 | B | C |
| ATOM | 2044 | CG | LEU | B | 360 | 32.910 | 74.992 | 38.924 | 1.00 | 17.82 | B | C |
| ATOM | 2045 | CD1 | LEU | B | 360 | 34.156 | 74.195 | 38.520 | 1.00 | 15.78 | B | C |
| ATOM | 2046 | CD2 | LEU | B | 360 | 33.219 | 75.937 | 40.073 | 1.00 | 15.51 | B | C |
| ATOM | 2047 | C | LEU | B | 360 | 30.927 | 73.953 | 36.870 | 1.00 | 20.12 | B | C |
| ATOM | 2048 | O | LEU | B | 360 | 31.207 | 72.793 | 37.169 | 1.00 | 19.65 | B | O |
| ATOM | 2049 | N | ASP | B | 361 | 29.681 | 74.418 | 36.850 | 1.00 | 21.34 | B | N |
| ATOM | 2050 | CA | ASP | B | 361 | 28.509 | 73.586 | 37.120 | 1.00 | 23.64 | B | C |
| ATOM | 2051 | CB | ASP | B | 361 | 28.170 | 72.798 | 35.844 | 1.00 | 25.61 | B | C |
| ATOM | 2052 | CG | ASP | B | 361 | 26.688 | 72.479 | 35.714 | 1.00 | 27.09 | B | C |
| ATOM | 2053 | OD1 | ASP | B | 361 | 25.849 | 73.206 | 36.292 | 1.00 | 29.93 | B | O |
| ATOM | 2054 | OD2 | ASP | B | 361 | 26.364 | 71.493 | 35.019 | 1.00 | 27.73 | B | O |
| ATOM | 2055 | C | ASP | B | 361 | 28.594 | 72.616 | 38.311 | 1.00 | 24.33 | B | C |
| ATOM | 2056 | O | ASP | B | 361 | 28.252 | 71.438 | 38.173 | 1.00 | 24.01 | B | O |
| ATOM | 2057 | N | VAL | B | 362 | 29.022 | 73.097 | 39.476 | 1.00 | 24.20 | B | N |
| ATOM | 2058 | CA | VAL | B | 362 | 29.108 | 72.221 | 40.646 | 1.00 | 24.84 | B | C |
| ATOM | 2059 | CB | VAL | B | 362 | 30.471 | 72.360 | 41.368 | 1.00 | 23.16 | B | C |
| ATOM | 2060 | CG1 | VAL | B | 362 | 31.590 | 71.899 | 40.456 | 1.00 | 22.13 | B | C |
| ATOM | 2061 | CG2 | VAL | B | 362 | 30.689 | 73.792 | 41.813 | 1.00 | 22.90 | B | C |
| ATOM | 2062 | C | VAL | B | 362 | 27.986 | 72.486 | 41.653 | 1.00 | 25.61 | B | C |
| ATOM | 2063 | O | VAL | B | 362 | 27.858 | 71.784 | 42.651 | 1.00 | 26.28 | B | O |
| ATOM | 2064 | N | HIS | B | 363 | 27.168 | 73.495 | 41.378 | 1.00 | 27.81 | B | N |
| ATOM | 2065 | CA | HIS | B | 363 | 26.057 | 73.855 | 42.251 | 1.00 | 28.99 | B | C |
| ATOM | 2066 | CB | HIS | B | 363 | 25.724 | 75.336 | 42.084 | 1.00 | 30.67 | B | C |
| ATOM | 2067 | CG | HIS | B | 363 | 25.151 | 75.976 | 43.310 | 1.00 | 34.13 | B | C |
| ATOM | 2068 | CD2 | HIS | B | 363 | 25.751 | 76.594 | 44.356 | 1.00 | 34.48 | B | C |
| ATOM | 2069 | ND1 | HIS | B | 363 | 23.793 | 76.056 | 43.542 | 1.00 | 34.72 | B | N |
| ATOM | 2070 | CE1 | HIS | B | 363 | 23.582 | 76.697 | 44.678 | 1.00 | 35.29 | B | C |
| ATOM | 2071 | NE2 | HIS | B | 363 | 24.753 | 77.034 | 45.191 | 1.00 | 36.08 | B | N |
| ATOM | 2072 | C | HIS | B | 363 | 24.828 | 73.029 | 41.914 | 1.00 | 29.83 | B | C |
| ATOM | 2073 | O | HIS | B | 363 | 24.461 | 72.902 | 40.749 | 1.00 | 29.18 | B | O |
| ATOM | 2074 | N | ALA | B | 364 | 24.194 | 72.467 | 42.938 | 1.00 | 31.56 | B | N |
| ATOM | 2075 | CA | ALA | B | 364 | 22.993 | 71.662 | 42.751 | 1.00 | 34.46 | B | C |
| ATOM | 2076 | CB | ALA | B | 364 | 22.700 | 70.866 | 44.014 | 1.00 | 33.03 | B | C |
| ATOM | 2077 | C | ALA | B | 364 | 21.813 | 72.574 | 42.421 | 1.00 | 36.94 | B | C |
| ATOM | 2078 | O | ALA | B | 364 | 21.624 | 73.615 | 43.045 | 1.00 | 39.51 | B | O |
| ATOM | 2079 | N | GLY | B | 365 | 21.015 | 72.186 | 41.438 | 1.00 | 38.98 | B | N |
| ATOM | 2080 | CA | GLY | B | 365 | 19.882 | 73.014 | 41.070 | 1.00 | 41.15 | B | C |
| ATOM | 2081 | C | GLY | B | 365 | 18.553 | 72.342 | 41.337 | 1.00 | 42.39 | B | C |
| ATOM | 2082 | O | GLY | B | 365 | 18.457 | 71.454 | 42.192 | 1.00 | 43.00 | B | O |
| ATOM | 2083 | N | ARG | B | 366 | 17.526 | 72.773 | 40.608 | 1.00 | 42.89 | B | N |
| ATOM | 2084 | CA | ARG | B | 366 | 16.191 | 72.212 | 40.748 | 1.00 | 43.25 | B | C |
| ATOM | 2085 | CB | ARG | B | 366 | 15.236 | 72.876 | 39.760 | 1.00 | 43.88 | B | C |
| ATOM | 2086 | CG | ARG | B | 366 | 15.530 | 74.349 | 39.582 | 1.00 | 44.57 | B | C |
| ATOM | 2087 | CD | ARG | B | 366 | 14.291 | 75.187 | 39.735 | 1.00 | 44.53 | B | C |
| ATOM | 2088 | NE | ARG | B | 366 | 14.223 | 76.150 | 38.647 | 1.00 | 44.28 | B | N |
| ATOM | 2089 | CZ | ARG | B | 366 | 13.817 | 75.845 | 37.423 | 1.00 | 44.90 | B | C |
| ATOM | 2090 | NH1 | ARG | B | 366 | 13.440 | 74.603 | 37.149 | 1.00 | 44.31 | B | N |
| ATOM | 2091 | NH2 | ARG | B | 366 | 13.821 | 76.766 | 36.468 | 1.00 | 44.56 | B | N |
| ATOM | 2092 | C | ARG | B | 366 | 16.284 | 70.725 | 40.482 | 1.00 | 43.56 | B | C |
| ATOM | 2093 | O | ARG | B | 366 | 15.523 | 69.930 | 41.039 | 1.00 | 44.36 | B | O |
| ATOM | 2094 | N | GLN | B | 367 | 17.220 | 70.351 | 39.619 | 1.00 | 44.87 | B | N |
| ATOM | 2095 | CA | GLN | B | 367 | 17.435 | 68.945 | 39.322 | 1.00 | 47.82 | B | C |
| ATOM | 2096 | CB | GLN | B | 367 | 18.196 | 68.793 | 38.006 | 1.00 | 51.38 | B | C |
| ATOM | 2097 | CG | GLN | B | 367 | 19.135 | 67.599 | 37.954 | 1.00 | 56.27 | B | C |
| ATOM | 2098 | CD | GLN | B | 367 | 20.536 | 67.981 | 37.496 | 1.00 | 59.36 | B | C |
| ATOM | 2099 | OE1 | GLN | B | 367 | 20.701 | 68.765 | 36.551 | 1.00 | 61.21 | B | O |
| ATOM | 2100 | NE2 | GLN | B | 367 | 21.553 | 67.430 | 38.161 | 1.00 | 60.03 | B | N |
| ATOM | 2101 | C | GLN | B | 367 | 18.265 | 68.448 | 40.502 | 1.00 | 47.74 | B | C |
| ATOM | 2102 | O | GLN | B | 367 | 18.643 | 69.247 | 41.359 | 1.00 | 49.78 | B | O |
| ATOM | 2103 | N | THR | B | 368 | 18.558 | 67.151 | 40.541 | 1.00 | 46.34 | B | N |
| ATOM | 2104 | CA | THR | B | 368 | 19.309 | 66.527 | 41.642 | 1.00 | 43.62 | B | C |
| ATOM | 2105 | CB | THR | B | 368 | 20.531 | 67.391 | 42.187 | 1.00 | 43.83 | B | C |
| ATOM | 2106 | OG1 | THR | B | 368 | 20.071 | 68.354 | 43.144 | 1.00 | 43.38 | B | O |
| ATOM | 2107 | CG2 | THR | B | 368 | 21.277 | 68.097 | 41.053 | 1.00 | 43.29 | B | C |
| ATOM | 2108 | C | THR | B | 368 | 18.339 | 66.250 | 42.797 | 1.00 | 41.61 | B | C |
| ATOM | 2109 | O | THR | B | 368 | 18.601 | 65.379 | 43.630 | 1.00 | 41.68 | B | O |
| ATOM | 2110 | N | PHE | B | 369 | 17.223 | 66.986 | 42.845 | 1.00 | 39.61 | B | N |
| ATOM | 2111 | CA | PHE | B | 369 | 16.226 | 66.769 | 43.889 | 1.00 | 37.15 | B | C |
| ATOM | 2112 | CB | PHE | B | 369 | 15.055 | 67.754 | 43.772 | 1.00 | 35.05 | B | C |
| ATOM | 2113 | CG | PHE | B | 369 | 14.069 | 67.668 | 44.922 | 1.00 | 34.03 | B | C |
| ATOM | 2114 | CD1 | PHE | B | 369 | 14.344 | 68.281 | 46.146 | 1.00 | 31.34 | B | C |
| ATOM | 2115 | CD2 | PHE | B | 369 | 12.873 | 66.962 | 44.784 | 1.00 | 32.46 | B | C |
| ATOM | 2116 | CE1 | PHE | B | 369 | 13.442 | 68.190 | 47.216 | 1.00 | 30.65 | B | C |
| ATOM | 2117 | CE2 | PHE | B | 369 | 11.966 | 66.868 | 45.849 | 1.00 | 30.71 | B | C |
| ATOM | 2118 | CZ | PHE | B | 369 | 12.254 | 67.483 | 47.066 | 1.00 | 29.09 | B | C |
| ATOM | 2119 | C | PHE | B | 369 | 15.724 | 65.356 | 43.662 | 1.00 | 37.23 | B | C |
| ATOM | 2120 | O | PHE | B | 369 | 15.044 | 65.084 | 42.672 | 1.00 | 36.67 | B | O |
| ATOM | 2121 | N | GLN | B | 370 | 16.083 | 64.462 | 44.579 | 1.00 | 37.46 | B | N |
| ATOM | 2122 | CA | GLN | B | 370 | 15.714 | 63.055 | 44.495 | 1.00 | 37.03 | B | C |
| ATOM | 2123 | CB | GLN | B | 370 | 14.201 | 62.897 | 44.441 | 1.00 | 37.54 | B | C |
| ATOM | 2124 | CG | GLN | B | 370 | 13.623 | 62.290 | 45.697 | 1.00 | 38.78 | B | C |
| ATOM | 2125 | CD | GLN | B | 370 | 12.425 | 63.058 | 46.177 | 1.00 | 40.45 | B | C |
| ATOM | 2126 | OE1 | GLN | B | 370 | 11.959 | 63.976 | 45.501 | 1.00 | 43.05 | B | O |
| ATOM | 2127 | NE2 | GLN | B | 370 | 11.913 | 62.696 | 47.348 | 1.00 | 40.82 | B | N |
| ATOM | 2128 | C | GLN | B | 370 | 16.361 | 62.411 | 43.269 | 1.00 | 37.33 | B | C |
| ATOM | 2129 | O | GLN | B | 370 | 15.806 | 61.491 | 42.658 | 1.00 | 36.63 | B | O |
| ATOM | 2130 | N | ARG | B | 371 | 17.537 | 62.926 | 42.917 | 1.00 | 36.70 | B | N |
| ATOM | 2131 | CA | ARG | B | 371 | 18.332 | 62.428 | 41.800 | 1.00 | 35.23 | B | C |
| ATOM | 2132 | CB | ARG | B | 371 | 18.294 | 63.399 | 40.613 | 1.00 | 34.72 | B | C |
| ATOM | 2133 | CG | ARG | B | 371 | 17.070 | 63.246 | 39.716 | 1.00 | 34.64 | B | C |
| ATOM | 2134 | CD | ARG | B | 371 | 17.014 | 61.878 | 39.026 | 1.00 | 34.86 | B | C |
| ATOM | 2135 | NE | ARG | B | 371 | 18.292 | 61.456 | 38.442 | 1.00 | 36.99 | B | N |
| ATOM | 2136 | CZ | ARG | B | 371 | 18.661 | 61.662 | 37.174 | 1.00 | 39.02 | B | C |
| ATOM | 2137 | NH1 | ARG | B | 371 | 17.857 | 62.292 | 36.327 | 1.00 | 39.44 | B | N |
| ATOM | 2138 | NH2 | ARG | B | 371 | 19.841 | 61.229 | 36.739 | 1.00 | 37.34 | B | N |
| ATOM | 2139 | C | ARG | B | 371 | 19.736 | 62.362 | 42.371 | 1.00 | 34.68 | B | C |
| ATOM | 2140 | O | ARG | B | 371 | 20.617 | 63.137 | 41.988 | 1.00 | 35.02 | B | O |
| ATOM | 2141 | N | PHE | B | 372 | 19.927 | 61.446 | 43.313 | 1.00 | 33.86 | B | N |
| ATOM | 2142 | CA | PHE | B | 372 | 21.218 | 61.284 | 43.963 | 1.00 | 33.79 | B | C |
| ATOM | 2143 | CB | PHE | B | 372 | 21.206 | 60.053 | 44.876 | 1.00 | 32.18 | B | C |
| ATOM | 2144 | CG | PHE | B | 372 | 22.178 | 60.154 | 46.012 | 1.00 | 32.84 | B | C |
| ATOM | 2145 | CD1 | PHE | B | 372 | 21.803 | 60.757 | 47.212 | 1.00 | 31.17 | B | C |
| ATOM | 2146 | CD2 | PHE | B | 372 | 23.492 | 59.709 | 45.862 | 1.00 | 30.92 | B | C |
| ATOM | 2147 | CE1 | PHE | B | 372 | 22.724 | 60.921 | 48.244 | 1.00 | 30.59 | B | C |
| ATOM | 2148 | CE2 | PHE | B | 372 | 24.419 | 59.868 | 46.884 | 1.00 | 30.94 | B | C |
| ATOM | 2149 | CZ | PHE | B | 372 | 24.037 | 60.476 | 48.080 | 1.00 | 31.31 | B | C |
| ATOM | 2150 | C | PHE | B | 372 | 22.369 | 61.174 | 42.963 | 1.00 | 33.85 | B | C |
| ATOM | 2151 | O | PHE | B | 372 | 23.454 | 61.713 | 43.186 | 1.00 | 33.32 | B | O |
| ATOM | 2152 | N | ASP | B | 373 | 22.124 | 60.472 | 41.863 | 1.00 | 34.20 | B | N |
| ATOM | 2153 | CA | ASP | B | 373 | 23.131 | 60.292 | 40.827 | 1.00 | 35.77 | B | C |
| ATOM | 2154 | CB | ASP | B | 373 | 22.551 | 59.464 | 39.683 | 1.00 | 37.41 | B | C |
| ATOM | 2155 | CG | ASP | B | 373 | 21.164 | 59.927 | 39.278 | 1.00 | 39.85 | B | C |
| ATOM | 2156 | OD1 | ASP | B | 373 | 20.638 | 60.872 | 39.909 | 1.00 | 41.35 | B | O |
| ATOM | 2157 | OD2 | ASP | B | 373 | 20.601 | 59.345 | 38.325 | 1.00 | 42.59 | B | O |
| ATOM | 2158 | C | ASP | B | 373 | 23.617 | 61.643 | 40.292 | 1.00 | 35.43 | B | C |
| ATOM | 2159 | O | ASP | B | 373 | 24.814 | 61.829 | 40.023 | 1.00 | 34.41 | B | O |
| ATOM | 2160 | N | LYS | B | 374 | 22.685 | 62.580 | 40.142 | 1.00 | 34.34 | B | N |
| ATOM | 2161 | CA | LYS | B | 374 | 23.015 | 63.909 | 39.646 | 1.00 | 34.66 | B | C |
| ATOM | 2162 | CB | LYS | B | 374 | 21.754 | 64.612 | 39.159 | 1.00 | 35.50 | B | C |
| ATOM | 2163 | CG | LYS | B | 374 | 21.011 | 63.813 | 38.109 | 1.00 | 38.20 | B | C |
| ATOM | 2164 | CD | LYS | B | 374 | 19.965 | 64.647 | 37.408 | 1.00 | 38.71 | B | C |
| ATOM | 2165 | CE | LYS | B | 374 | 20.475 | 65.135 | 36.064 | 1.00 | 41.14 | B | C |
| ATOM | 2166 | NZ | LYS | B | 374 | 19.363 | 65.677 | 35.230 | 1.00 | 42.69 | B | N |
| ATOM | 2167 | C | LYS | B | 374 | 23.693 | 64.740 | 40.722 | 1.00 | 34.35 | B | C |
| ATOM | 2168 | O | LYS | B | 374 | 24.392 | 65.712 | 40.423 | 1.00 | 33.83 | B | O |
| ATOM | 2169 | N | PHE | B | 375 | 23.487 | 64.358 | 41.978 | 1.00 | 34.80 | B | N |
| ATOM | 2170 | CA | PHE | B | 375 | 24.112 | 65.067 | 43.087 | 1.00 | 35.22 | B | C |
| ATOM | 2171 | CB | PHE | B | 375 | 23.399 | 64.744 | 44.407 | 1.00 | 33.47 | B | C |
| ATOM | 2172 | CG | PHE | B | 375 | 24.267 | 64.942 | 45.616 | 1.00 | 33.39 | B | C |
| ATOM | 2173 | CD1 | PHE | B | 375 | 24.644 | 66.228 | 46.011 | 1.00 | 33.64 | B | C |
| ATOM | 2174 | CD2 | PHE | B | 375 | 24.779 | 63.846 | 46.309 | 1.00 | 33.30 | B | C |
| ATOM | 2175 | CE1 | PHE | B | 375 | 25.525 | 66.425 | 47.074 | 1.00 | 32.00 | B | C |
| ATOM | 2176 | CE2 | PHE | B | 375 | 25.660 | 64.026 | 47.374 | 1.00 | 32.60 | B | C |
| ATOM | 2177 | CZ | PHE | B | 375 | 26.036 | 65.324 | 47.755 | 1.00 | 32.89 | B | C |
| ATOM | 2178 | C | PHE | B | 375 | 25.586 | 64.647 | 43.177 | 1.00 | 35.28 | B | C |
| ATOM | 2179 | O | PHE | B | 375 | 26.482 | 65.488 | 43.327 | 1.00 | 34.36 | B | O |
| ATOM | 2180 | N | ASN | B | 376 | 25.828 | 63.343 | 43.074 | 1.00 | 36.73 | B | N |
| ATOM | 2181 | CA | ASN | B | 376 | 27.179 | 62.806 | 43.153 | 1.00 | 40.22 | B | C |
| ATOM | 2182 | CB | ASN | B | 376 | 27.129 | 61.282 | 43.286 | 1.00 | 41.07 | B | C |
| ATOM | 2183 | CG | ASN | B | 376 | 28.012 | 60.770 | 44.410 | 1.00 | 43.41 | B | C |
| ATOM | 2184 | OD1 | ASN | B | 376 | 28.974 | 61.434 | 44.821 | 1.00 | 44.40 | B | O |
| ATOM | 2185 | ND2 | ASN | B | 376 | 27.692 | 59.586 | 44.915 | 1.00 | 42.85 | B | N |
| ATOM | 2186 | C | ASN | B | 376 | 28.043 | 63.192 | 41.951 | 1.00 | 42.48 | B | C |
| ATOM | 2187 | O | ASN | B | 376 | 29.268 | 63.320 | 42.058 | 1.00 | 43.10 | B | O |
| ATOM | 2188 | N | ASP | B | 377 | 27.415 | 63.374 | 40.799 | 1.00 | 44.10 | B | N |
| ATOM | 2189 | CA | ASP | B | 377 | 28.180 | 63.756 | 39.634 | 1.00 | 46.39 | B | C |
| ATOM | 2190 | CB | ASP | B | 377 | 27.491 | 63.256 | 38.367 | 1.00 | 49.21 | B | C |
| ATOM | 2191 | CG | ASP | B | 377 | 27.947 | 61.848 | 37.987 | 1.00 | 52.90 | B | C |
| ATOM | 2192 | OD1 | ASP | B | 377 | 28.653 | 61.211 | 38.808 | 1.00 | 53.90 | B | O |
| ATOM | 2193 | OD2 | ASP | B | 377 | 27.609 | 61.382 | 36.875 | 1.00 | 55.09 | B | O |
| ATOM | 2194 | C | ASP | B | 377 | 28.387 | 65.265 | 39.617 | 1.00 | 46.66 | B | C |
| ATOM | 2195 | O | ASP | B | 377 | 28.990 | 65.812 | 38.698 | 1.00 | 47.67 | B | O |
| ATOM | 2196 | N | LYS | B | 378 | 27.893 | 65.930 | 40.656 | 1.00 | 47.51 | B | N |
| ATOM | 2197 | CA | LYS | B | 378 | 28.053 | 67.373 | 40.788 | 1.00 | 47.57 | B | C |
| ATOM | 2198 | CB | LYS | B | 378 | 27.036 | 67.935 | 41.785 | 1.00 | 48.77 | B | C |
| ATOM | 2199 | CG | LYS | B | 378 | 26.396 | 69.239 | 41.354 | 1.00 | 49.53 | B | C |
| ATOM | 2200 | CD | LYS | B | 378 | 25.304 | 68.997 | 40.331 | 1.00 | 50.90 | B | C |
| ATOM | 2201 | CE | LYS | B | 378 | 25.427 | 69.945 | 39.157 | 1.00 | 50.14 | B | C |
| ATOM | 2202 | NZ | LYS | B | 378 | 24.154 | 70.673 | 38.934 | 1.00 | 53.59 | B | N |
| ATOM | 2203 | C | LYS | B | 378 | 29.470 | 67.600 | 41.305 | 1.00 | 46.72 | B | C |
| ATOM | 2204 | O | LYS | B | 378 | 30.011 | 68.707 | 41.238 | 1.00 | 45.73 | B | O |
| ATOM | 2205 | N | TYR | B | 379 | 30.060 | 66.529 | 41.828 | 1.00 | 46.65 | B | N |
| ATOM | 2206 | CA | TYR | B | 379 | 31.415 | 66.574 | 42.356 | 1.00 | 47.10 | B | C |
| ATOM | 2207 | CB | TYR | B | 379 | 31.725 | 65.307 | 43.156 | 1.00 | 51.31 | B | C |
| ATOM | 2208 | CG | TYR | B | 379 | 31.299 | 65.351 | 44.605 | 1.00 | 56.26 | B | C |
| ATOM | 2209 | CD1 | TYR | B | 379 | 30.838 | 64.202 | 45.244 | 1.00 | 58.32 | B | C |
| ATOM | 2210 | CE1 | TYR | B | 379 | 30.447 | 64.228 | 46.579 | 1.00 | 59.67 | B | C |
| ATOM | 2211 | CD2 | TYR | B | 379 | 31.358 | 66.537 | 45.340 | 1.00 | 58.83 | B | C |
| ATOM | 2212 | CE2 | TYR | B | 379 | 30.968 | 66.575 | 46.677 | 1.00 | 59.92 | B | C |
| ATOM | 2213 | CZ | TYR | B | 379 | 30.514 | 65.417 | 47.291 | 1.00 | 59.84 | B | C |
| ATOM | 2214 | OH | TYR | B | 379 | 30.140 | 65.442 | 48.614 | 1.00 | 58.95 | B | O |
| ATOM | 2215 | C | TYR | B | 379 | 32.390 | 66.668 | 41.197 | 1.00 | 45.09 | B | C |
| ATOM | 2216 | O | TYR | B | 379 | 33.602 | 66.752 | 41.402 | 1.00 | 45.89 | B | O |
| ATOM | 2217 | N | ASN | B | 380 | 31.853 | 66.629 | 39.979 | 1.00 | 41.12 | B | N |
| ATOM | 2218 | CA | ASN | B | 380 | 32.674 | 66.713 | 38.776 | 1.00 | 35.86 | B | C |
| ATOM | 2219 | CB | ASN | B | 380 | 32.114 | 65.809 | 37.679 | 1.00 | 34.89 | B | C |
| ATOM | 2220 | CG | ASN | B | 380 | 32.213 | 64.347 | 38.029 | 1.00 | 34.29 | B | C |
| ATOM | 2221 | OD1 | ASN | B | 380 | 33.112 | 63.929 | 38.760 | 1.00 | 34.17 | B | O |
| ATOM | 2222 | ND2 | ASN | B | 380 | 31.288 | 63.552 | 37.505 | 1.00 | 34.67 | B | N |
| ATOM | 2223 | C | ASN | B | 380 | 32.720 | 68.138 | 38.252 | 1.00 | 32.45 | B | C |
| ATOM | 2224 | O | ASN | B | 380 | 31.767 | 68.605 | 37.630 | 1.00 | 31.23 | B | O |
| ATOM | 2225 | N | PRO | B | 381 | 33.827 | 68.853 | 38.506 | 1.00 | 28.96 | B | N |
| ATOM | 2226 | CD | PRO | B | 381 | 35.030 | 68.427 | 39.235 | 1.00 | 27.13 | B | C |
| ATOM | 2227 | CA | PRO | B | 381 | 33.931 | 70.232 | 38.021 | 1.00 | 28.44 | B | C |
| ATOM | 2228 | CB | PRO | B | 381 | 35.316 | 70.683 | 38.483 | 1.00 | 26.51 | B | C |
| ATOM | 2229 | CG | PRO | B | 381 | 35.712 | 69.720 | 39.535 | 1.00 | 27.82 | B | C |
| ATOM | 2230 | C | PRO | B | 381 | 33.803 | 70.242 | 36.494 | 1.00 | 28.13 | B | C |
| ATOM | 2231 | O | PRO | B | 381 | 34.384 | 69.399 | 35.810 | 1.00 | 27.58 | B | O |
| ATOM | 2232 | N | VAL | B | 382 | 33.035 | 71.191 | 35.974 | 1.00 | 28.20 | B | N |
| ATOM | 2233 | CA | VAL | B | 382 | 32.806 | 71.313 | 34.539 | 1.00 | 28.55 | B | C |
| ATOM | 2234 | CB | VAL | B | 382 | 34.046 | 71.926 | 33.827 | 1.00 | 29.16 | B | C |
| ATOM | 2235 | CG1 | VAL | B | 382 | 35.025 | 70.851 | 33.434 | 1.00 | 31.47 | B | C |
| ATOM | 2236 | CG2 | VAL | B | 382 | 33.605 | 72.703 | 32.607 | 1.00 | 29.55 | B | C |
| ATOM | 2237 | C | VAL | B | 382 | 32.415 | 69.973 | 33.900 | 1.00 | 28.59 | B | C |
| ATOM | 2238 | O | VAL | B | 382 | 32.619 | 69.751 | 32.707 | 1.00 | 28.52 | B | O |
| ATOM | 2239 | N | GLY | B | 383 | 31.845 | 69.087 | 34.712 | 1.00 | 27.99 | B | N |
| ATOM | 2240 | CA | GLY | B | 383 | 31.398 | 67.789 | 34.228 | 1.00 | 25.96 | B | C |
| ATOM | 2241 | C | GLY | B | 383 | 32.470 | 66.762 | 33.917 | 1.00 | 25.12 | B | C |
| ATOM | 2242 | O | GLY | B | 383 | 32.177 | 65.723 | 33.325 | 1.00 | 24.74 | B | O |
| ATOM | 2243 | N | ALA | B | 384 | 33.708 | 67.033 | 34.315 | 1.00 | 24.33 | B | N |
| ATOM | 2244 | CA | ALA | B | 384 | 34.809 | 66.114 | 34.048 | 1.00 | 24.14 | B | C |
| ATOM | 2245 | CB | ALA | B | 384 | 35.964 | 66.873 | 33.421 | 1.00 | 23.38 | B | C |
| ATOM | 2246 | C | ALA | B | 384 | 35.298 | 65.374 | 35.292 | 1.00 | 23.98 | B | C |
| ATOM | 2247 | O | ALA | B | 384 | 35.795 | 65.987 | 36.228 | 1.00 | 25.48 | B | O |
| ATOM | 2248 | N | SER | B | 385 | 35.167 | 64.052 | 35.293 | 1.00 | 24.38 | B | N |
| ATOM | 2249 | CA | SER | B | 385 | 35.618 | 63.256 | 36.425 | 1.00 | 24.13 | B | C |
| ATOM | 2250 | CB | SER | B | 385 | 35.240 | 61.783 | 36.223 | 1.00 | 23.81 | B | C |
| ATOM | 2251 | OG | SER | B | 385 | 36.146 | 61.123 | 35.357 | 1.00 | 28.64 | B | O |
| ATOM | 2252 | C | SER | B | 385 | 37.129 | 63.406 | 36.595 | 1.00 | 23.64 | B | C |
| ATOM | 2253 | O | SER | B | 385 | 37.651 | 63.294 | 37.700 | 1.00 | 24.76 | B | O |
| ATOM | 2254 | N | GLU | B | 386 | 37.823 | 63.667 | 35.491 | 1.00 | 23.55 | B | N |
| ATOM | 2255 | CA | GLU | B | 386 | 39.275 | 63.854 | 35.505 | 1.00 | 24.57 | B | C |
| ATOM | 2256 | CB | GLU | B | 386 | 39.797 | 64.156 | 34.092 | 1.00 | 24.25 | B | C |
| ATOM | 2257 | CG | GLU | B | 386 | 39.785 | 62.977 | 33.131 | 1.00 | 25.77 | B | C |
| ATOM | 2258 | CD | GLU | B | 386 | 38.472 | 62.851 | 32.368 | 1.00 | 28.39 | B | C |
| ATOM | 2259 | OE1 | GLU | B | 386 | 38.315 | 61.867 | 31.608 | 1.00 | 31.43 | B | O |
| ATOM | 2260 | OE2 | GLU | B | 386 | 37.595 | 63.729 | 32.527 | 1.00 | 28.19 | B | O |
| ATOM | 2261 | C | GLU | B | 386 | 39.642 | 65.023 | 36.413 | 1.00 | 24.03 | B | C |
| ATOM | 2262 | O | GLU | B | 386 | 40.647 | 64.985 | 37.116 | 1.00 | 23.46 | B | O |
| ATOM | 2263 | N | LEU | B | 387 | 38.821 | 66.069 | 36.377 | 1.00 | 24.13 | B | N |
| ATOM | 2264 | CA | LEU | B | 387 | 39.050 | 67.260 | 37.185 | 1.00 | 23.70 | B | C |
| ATOM | 2265 | CB | LEU | B | 387 | 38.250 | 68.429 | 36.611 | 1.00 | 23.69 | B | C |
| ATOM | 2266 | CG | LEU | B | 387 | 38.680 | 68.872 | 35.204 | 1.00 | 21.33 | B | C |
| ATOM | 2267 | CD1 | LEU | B | 387 | 37.868 | 70.077 | 34.779 | 1.00 | 19.74 | B | C |
| ATOM | 2268 | CD2 | LEU | B | 387 | 40.157 | 69.209 | 35.190 | 1.00 | 20.22 | B | C |
| ATOM | 2269 | C | LEU | B | 387 | 38.692 | 67.028 | 38.654 | 1.00 | 24.12 | B | C |
| ATOM | 2270 | O | LEU | B | 387 | 39.276 | 67.639 | 39.545 | 1.00 | 23.80 | B | O |
| ATOM | 2271 | N | ARG | B | 388 | 37.730 | 66.148 | 38.902 | 1.00 | 24.26 | B | N |
| ATOM | 2272 | CA | ARG | B | 388 | 37.351 | 65.826 | 40.266 | 1.00 | 26.77 | B | C |
| ATOM | 2273 | CB | ARG | B | 388 | 36.080 | 64.969 | 40.285 | 1.00 | 31.44 | B | C |
| ATOM | 2274 | CG | ARG | B | 388 | 35.985 | 64.003 | 41.464 | 1.00 | 36.73 | B | C |
| ATOM | 2275 | CD | ARG | B | 388 | 34.546 | 63.779 | 41.897 | 1.00 | 41.54 | B | C |
| ATOM | 2276 | NE | ARG | B | 388 | 34.437 | 62.728 | 42.909 | 1.00 | 47.47 | B | N |
| ATOM | 2277 | CZ | ARG | B | 388 | 33.298 | 62.129 | 43.259 | 1.00 | 50.25 | B | C |
| ATOM | 2278 | NH1 | ARG | B | 388 | 32.148 | 62.470 | 42.685 | 1.00 | 51.10 | B | N |
| ATOM | 2279 | NH2 | ARG | B | 388 | 33.308 | 61.178 | 44.184 | 1.00 | 52.23 | B | N |
| ATOM | 2280 | C | ARG | B | 388 | 38.518 | 65.042 | 40.865 | 1.00 | 26.39 | B | C |
| ATOM | 2281 | O | ARG | B | 388 | 38.956 | 65.310 | 41.980 | 1.00 | 25.36 | B | O |
| ATOM | 2282 | N | ASP | B | 389 | 39.023 | 64.076 | 40.105 | 1.00 | 24.86 | B | N |
| ATOM | 2283 | CA | ASP | B | 389 | 40.138 | 63.249 | 40.546 | 1.00 | 23.77 | B | C |
| ATOM | 2284 | CB | ASP | B | 389 | 40.513 | 62.250 | 39.459 | 1.00 | 23.75 | B | C |
| ATOM | 2285 | CG | ASP | B | 389 | 39.539 | 61.107 | 39.364 | 1.00 | 28.25 | B | C |
| ATOM | 2286 | OD1 | ASP | B | 389 | 39.637 | 60.332 | 38.390 | 1.00 | 31.15 | B | O |
| ATOM | 2287 | OD2 | ASP | B | 389 | 38.673 | 60.979 | 40.259 | 1.00 | 31.98 | B | O |
| ATOM | 2288 | C | ASP | B | 389 | 41.365 | 64.075 | 40.862 | 1.00 | 23.49 | B | C |
| ATOM | 2289 | O | ASP | B | 389 | 42.142 | 63.738 | 41.755 | 1.00 | 23.36 | B | O |
| ATOM | 2290 | N | LEU | B | 390 | 41.537 | 65.161 | 40.117 | 1.00 | 22.63 | B | N |
| ATOM | 2291 | CA | LEU | B | 390 | 42.698 | 66.022 | 40.267 | 1.00 | 22.06 | B | C |
| ATOM | 2292 | CB | LEU | B | 390 | 42.963 | 66.729 | 38.934 | 1.00 | 20.86 | B | C |
| ATOM | 2293 | CG | LEU | B | 390 | 44.052 | 67.806 | 38.886 | 1.00 | 22.56 | B | C |
| ATOM | 2294 | CD1 | LEU | B | 390 | 45.400 | 67.193 | 39.222 | 1.00 | 19.78 | B | C |
| ATOM | 2295 | CD2 | LEU | B | 390 | 44.085 | 68.439 | 37.497 | 1.00 | 20.49 | B | C |
| ATOM | 2296 | C | LEU | B | 390 | 42.651 | 67.057 | 41.388 | 1.00 | 21.84 | B | C |
| ATOM | 2297 | O | LEU | B | 390 | 43.635 | 67.239 | 42.107 | 1.00 | 21.39 | B | O |
| ATOM | 2298 | N | TYR | B | 391 | 41.511 | 67.725 | 41.537 | 1.00 | 22.43 | B | N |
| ATOM | 2299 | CA | TYR | B | 391 | 41.353 | 68.777 | 42.537 | 1.00 | 21.24 | B | C |
| ATOM | 2300 | CB | TYR | B | 391 | 40.598 | 69.962 | 41.907 | 1.00 | 20.18 | B | C |
| ATOM | 2301 | CG | TYR | B | 391 | 41.349 | 70.689 | 40.812 | 1.00 | 20.08 | B | C |
| ATOM | 2302 | CD1 | TYR | B | 391 | 42.301 | 71.665 | 41.120 | 1.00 | 19.66 | B | C |
| ATOM | 2303 | CE1 | TYR | B | 391 | 43.002 | 72.329 | 40.125 | 1.00 | 19.77 | B | C |
| ATOM | 2304 | CD2 | TYR | B | 391 | 41.116 | 70.397 | 39.465 | 1.00 | 20.86 | B | C |
| ATOM | 2305 | CE2 | TYR | B | 391 | 41.821 | 71.061 | 38.450 | 1.00 | 21.83 | B | C |
| ATOM | 2306 | CZ | TYR | B | 391 | 42.762 | 72.022 | 38.790 | 1.00 | 21.87 | B | C |
| ATOM | 2307 | OH | TYR | B | 391 | 43.477 | 72.665 | 37.802 | 1.00 | 20.62 | B | O |
| ATOM | 2308 | C | TYR | B | 391 | 40.644 | 68.396 | 43.843 | 1.00 | 21.00 | B | C |
| ATOM | 2309 | O | TYR | B | 391 | 40.834 | 69.060 | 44.866 | 1.00 | 20.72 | B | O |
| ATOM | 2310 | N | LEU | B | 392 | 39.835 | 67.340 | 43.813 | 1.00 | 19.40 | B | N |
| ATOM | 2311 | CA | LEU | B | 392 | 39.065 | 66.957 | 44.987 | 1.00 | 19.39 | B | C |
| ATOM | 2312 | CB | LEU | B | 392 | 37.574 | 67.179 | 44.712 | 1.00 | 17.93 | B | C |
| ATOM | 2313 | CG | LEU | B | 392 | 37.188 | 68.530 | 44.094 | 1.00 | 18.16 | B | C |
| ATOM | 2314 | CD1 | LEU | B | 392 | 35.716 | 68.532 | 43.729 | 1.00 | 17.69 | B | C |
| ATOM | 2315 | CD2 | LEU | B | 392 | 37.488 | 69.651 | 45.072 | 1.00 | 18.77 | B | C |
| ATOM | 2316 | C | LEU | B | 392 | 39.267 | 65.547 | 45.506 | 1.00 | 21.39 | B | C |
| ATOM | 2317 | O | LEU | B | 392 | 38.351 | 64.968 | 46.096 | 1.00 | 22.96 | B | O |
| ATOM | 2318 | N | LYS | B | 393 | 40.453 | 64.987 | 45.296 | 1.00 | 20.58 | B | N |
| ATOM | 2319 | CA | LYS | B | 393 | 40.732 | 63.642 | 45.779 | 1.00 | 20.28 | B | C |
| ATOM | 2320 | CB | LYS | B | 393 | 40.722 | 62.646 | 44.628 | 1.00 | 21.73 | B | C |
| ATOM | 2321 | CG | LYS | B | 393 | 39.344 | 62.399 | 44.067 | 1.00 | 23.93 | B | C |
| ATOM | 2322 | CD | LYS | B | 393 | 39.037 | 60.927 | 44.029 | 1.00 | 27.13 | B | C |
| ATOM | 2323 | CE | LYS | B | 393 | 37.717 | 60.668 | 43.331 | 1.00 | 29.46 | B | C |
| ATOM | 2324 | NZ | LYS | B | 393 | 37.468 | 59.207 | 43.190 | 1.00 | 33.09 | B | N |
| ATOM | 2325 | C | LYS | B | 393 | 42.079 | 63.625 | 46.465 | 1.00 | 20.65 | B | C |
| ATOM | 2326 | O | LYS | B | 393 | 42.925 | 64.475 | 46.200 | 1.00 | 20.36 | B | O |
| ATOM | 2327 | N | THR | B | 394 | 42.280 | 62.660 | 47.354 | 1.00 | 20.80 | B | N |
| ATOM | 2328 | CA | THR | B | 394 | 43.539 | 62.567 | 48.080 | 1.00 | 21.33 | B | C |
| ATOM | 2329 | CB | THR | B | 394 | 43.308 | 62.044 | 49.530 | 1.00 | 18.87 | B | C |
| ATOM | 2330 | OG1 | THR | B | 394 | 42.801 | 60.707 | 49.494 | 1.00 | 20.22 | B | O |
| ATOM | 2331 | CG2 | THR | B | 394 | 42.310 | 62.924 | 50.253 | 1.00 | 16.48 | B | C |
| ATOM | 2332 | C | THR | B | 394 | 44.547 | 61.675 | 47.358 | 1.00 | 22.12 | B | C |
| ATOM | 2333 | O | THR | B | 394 | 45.761 | 61.850 | 47.490 | 1.00 | 22.02 | B | O |
| ATOM | 2334 | N | ASP | B | 395 | 44.041 | 60.724 | 46.584 | 1.00 | 24.00 | B | N |
| ATOM | 2335 | CA | ASP | B | 395 | 44.904 | 59.810 | 45.852 | 1.00 | 26.84 | B | C |
| ATOM | 2336 | CB | ASP | B | 395 | 44.521 | 58.361 | 46.157 | 1.00 | 30.73 | B | C |
| ATOM | 2337 | CG | ASP | B | 395 | 45.548 | 57.363 | 45.638 | 1.00 | 35.34 | B | C |
| ATOM | 2338 | OD1 | ASP | B | 395 | 46.745 | 57.727 | 45.550 | 1.00 | 38.17 | B | O |
| ATOM | 2339 | OD2 | ASP | B | 395 | 45.162 | 56.216 | 45.320 | 1.00 | 38.78 | B | O |
| ATOM | 2340 | C | ASP | B | 395 | 44.835 | 60.042 | 44.351 | 1.00 | 26.30 | B | C |
| ATOM | 2341 | O | ASP | B | 395 | 43.788 | 59.860 | 43.734 | 1.00 | 26.42 | B | O |
| ATOM | 2342 | N | ASN | B | 396 | 45.958 | 60.452 | 43.771 | 1.00 | 25.83 | B | N |
| ATOM | 2343 | CA | ASN | B | 396 | 46.040 | 60.688 | 42.339 | 1.00 | 25.38 | B | C |
| ATOM | 2344 | CB | ASN | B | 396 | 45.254 | 61.947 | 41.946 | 1.00 | 24.52 | B | C |
| ATOM | 2345 | CG | ASN | B | 396 | 45.795 | 63.209 | 42.590 | 1.00 | 23.06 | B | C |
| ATOM | 2346 | OD1 | ASN | B | 396 | 45.104 | 64.225 | 42.651 | 1.00 | 23.22 | B | O |
| ATOM | 2347 | ND2 | ASN | B | 396 | 47.030 | 63.154 | 43.071 | 1.00 | 22.11 | B | N |
| ATOM | 2348 | C | ASN | B | 396 | 47.491 | 60.814 | 41.911 | 1.00 | 25.00 | B | C |
| ATOM | 2349 | O | ASN | B | 396 | 48.399 | 60.578 | 42.704 | 1.00 | 26.39 | B | O |
| ATOM | 2350 | N | TYR | B | 397 | 47.705 | 61.203 | 40.661 | 1.00 | 25.67 | B | N |
| ATOM | 2351 | CA | TYR | B | 397 | 49.050 | 61.330 | 40.126 | 1.00 | 25.95 | B | C |
| ATOM | 2352 | CB | TYR | B | 397 | 49.002 | 61.753 | 38.658 | 1.00 | 26.80 | B | C |
| ATOM | 2353 | CG | TYR | B | 397 | 50.326 | 61.578 | 37.952 | 1.00 | 27.39 | B | C |
| ATOM | 2354 | CD1 | TYR | B | 397 | 51.252 | 62.622 | 37.900 | 1.00 | 27.82 | B | C |
| ATOM | 2355 | CE1 | TYR | B | 397 | 52.486 | 62.460 | 37.273 | 1.00 | 29.95 | B | C |
| ATOM | 2356 | CD2 | TYR | B | 397 | 50.665 | 60.361 | 37.355 | 1.00 | 28.69 | B | C |
| ATOM | 2357 | CE2 | TYR | B | 397 | 51.900 | 60.186 | 36.722 | 1.00 | 29.89 | B | C |
| ATOM | 2358 | CZ | TYR | B | 397 | 52.804 | 61.238 | 36.684 | 1.00 | 31.11 | B | C |
| ATOM | 2359 | OH | TYR | B | 397 | 54.019 | 61.072 | 36.054 | 1.00 | 32.35 | B | O |
| ATOM | 2360 | C | TYR | B | 397 | 49.933 | 62.291 | 40.902 | 1.00 | 26.44 | B | C |
| ATOM | 2361 | O | TYR | B | 397 | 51.138 | 62.066 | 41.021 | 1.00 | 26.73 | B | O |
| ATOM | 2362 | N | ILE | B | 398 | 49.353 | 63.372 | 41.414 | 1.00 | 26.86 | B | N |
| ATOM | 2363 | CA | ILE | B | 398 | 50.142 | 64.327 | 42.184 | 1.00 | 26.76 | B | C |
| ATOM | 2364 | CB | ILE | B | 398 | 49.846 | 65.789 | 41.765 | 1.00 | 25.49 | B | C |
| ATOM | 2365 | CG2 | ILE | B | 398 | 50.410 | 66.038 | 40.384 | 1.00 | 25.58 | B | C |
| ATOM | 2366 | CG1 | ILE | B | 398 | 48.344 | 66.065 | 41.766 | 1.00 | 23.92 | B | C |
| ATOM | 2367 | CD1 | ILE | B | 398 | 48.016 | 67.532 | 41.809 | 1.00 | 21.14 | B | C |
| ATOM | 2368 | C | ILE | B | 398 | 49.927 | 64.162 | 43.691 | 1.00 | 27.30 | B | C |
| ATOM | 2369 | O | ILE | B | 398 | 50.118 | 65.099 | 44.460 | 1.00 | 27.82 | B | O |
| ATOM | 2370 | N | ASN | B | 399 | 49.533 | 62.956 | 44.096 | 1.00 | 27.79 | B | N |
| ATOM | 2371 | CA | ASN | B | 399 | 49.307 | 62.620 | 45.504 | 1.00 | 27.28 | B | C |
| ATOM | 2372 | CB | ASN | B | 399 | 50.651 | 62.527 | 46.239 | 1.00 | 27.97 | B | C |
| ATOM | 2373 | CG | ASN | B | 399 | 51.632 | 61.588 | 45.553 | 1.00 | 30.20 | B | C |
| ATOM | 2374 | OD1 | ASN | B | 399 | 51.284 | 60.462 | 45.190 | 1.00 | 32.08 | B | O |
| ATOM | 2375 | ND2 | ASN | B | 399 | 52.867 | 62.049 | 45.373 | 1.00 | 28.40 | B | N |
| ATOM | 2376 | C | ASN | B | 399 | 48.380 | 63.568 | 46.267 | 1.00 | 25.97 | B | C |
| ATOM | 2377 | O | ASN | B | 399 | 48.713 | 64.022 | 47.358 | 1.00 | 25.53 | B | O |
| ATOM | 2378 | N | GLU | B | 400 | 47.221 | 63.859 | 45.687 | 1.00 | 25.65 | B | N |
| ATOM | 2379 | CA | GLU | B | 400 | 46.246 | 64.727 | 46.324 | 1.00 | 24.76 | B | C |
| ATOM | 2380 | C | GLU | B | 400 | 46.715 | 66.090 | 46.795 | 1.00 | 23.41 | B | C |
| ATOM | 2381 | O | GLU | B | 400 | 46.075 | 66.710 | 47.641 | 1.00 | 23.38 | B | O |
| ATOM | 2382 | N | GLU | B | 401 | 47.812 | 66.580 | 46.236 | 1.00 | 22.71 | B | N |
| ATOM | 2383 | CA | GLU | B | 401 | 48.346 | 67.876 | 46.643 | 1.00 | 22.67 | B | C |
| ATOM | 2384 | CB | GLU | B | 401 | 49.654 | 68.133 | 45.907 | 1.00 | 23.05 | B | C |
| ATOM | 2385 | CG | GLU | B | 401 | 50.262 | 69.474 | 46.213 | 1.00 | 24.75 | B | C |
| ATOM | 2386 | CD | GLU | B | 401 | 51.475 | 69.752 | 45.365 | 1.00 | 26.75 | B | C |
| ATOM | 2387 | OE1 | GLU | B | 401 | 52.364 | 68.875 | 45.315 | 1.00 | 25.90 | B | O |
| ATOM | 2388 | OE2 | GLU | B | 401 | 51.537 | 70.843 | 44.751 | 1.00 | 26.02 | B | O |
| ATOM | 2389 | C | GLU | B | 401 | 47.415 | 69.085 | 46.466 | 1.00 | 23.17 | B | C |
| ATOM | 2390 | O | GLU | B | 401 | 47.432 | 70.008 | 47.288 | 1.00 | 23.22 | B | O |
| ATOM | 2391 | N | TYR | B | 402 | 46.617 | 69.091 | 45.399 | 1.00 | 21.60 | B | N |
| ATOM | 2392 | CA | TYR | B | 402 | 45.694 | 70.199 | 45.128 | 1.00 | 21.31 | B | C |
| ATOM | 2393 | CB | TYR | B | 402 | 45.119 | 70.077 | 43.706 | 1.00 | 20.97 | B | C |
| ATOM | 2394 | CG | TYR | B | 402 | 46.049 | 70.567 | 42.610 | 1.00 | 21.79 | B | C |
| ATOM | 2395 | CD1 | TYR | B | 402 | 47.311 | 71.078 | 42.914 | 1.00 | 21.50 | B | C |
| ATOM | 2396 | CE1 | TYR | B | 402 | 48.161 | 71.554 | 41.913 | 1.00 | 21.86 | B | C |
| ATOM | 2397 | CD2 | TYR | B | 402 | 45.658 | 70.540 | 41.271 | 1.00 | 20.00 | B | C |
| ATOM | 2398 | CE2 | TYR | B | 402 | 46.501 | 71.013 | 40.263 | 1.00 | 20.93 | B | C |
| ATOM | 2399 | CZ | TYR | B | 402 | 47.749 | 71.520 | 40.592 | 1.00 | 21.54 | B | C |
| ATOM | 2400 | OH | TYR | B | 402 | 48.583 | 72.013 | 39.614 | 1.00 | 19.51 | B | O |
| ATOM | 2401 | C | TYR | B | 402 | 44.547 | 70.245 | 46.139 | 1.00 | 20.17 | B | C |
| ATOM | 2402 | O | TYR | B | 402 | 44.116 | 71.318 | 46.554 | 1.00 | 18.77 | B | O |
| ATOM | 2403 | N | PHE | B | 403 | 44.054 | 69.068 | 46.512 | 1.00 | 19.31 | B | N |
| ATOM | 2404 | CA | PHE | B | 403 | 42.969 | 68.941 | 47.473 | 1.00 | 18.59 | B | C |
| ATOM | 2405 | CB | PHE | B | 403 | 42.532 | 67.478 | 47.575 | 1.00 | 17.58 | B | C |
| ATOM | 2406 | CG | PHE | B | 403 | 41.262 | 67.277 | 48.341 | 1.00 | 16.37 | B | C |
| ATOM | 2407 | CD1 | PHE | B | 403 | 40.272 | 68.254 | 48.341 | 1.00 | 15.96 | B | C |
| ATOM | 2408 | CD2 | PHE | B | 403 | 41.056 | 66.111 | 49.068 | 1.00 | 16.31 | B | C |
| ATOM | 2409 | CE1 | PHE | B | 403 | 39.092 | 68.072 | 49.056 | 1.00 | 16.40 | B | C |
| ATOM | 2410 | CE2 | PHE | B | 403 | 39.880 | 65.917 | 49.784 | 1.00 | 17.01 | B | C |
| ATOM | 2411 | CZ | PHE | B | 403 | 38.895 | 66.902 | 49.779 | 1.00 | 16.41 | B | C |
| ATOM | 2412 | C | PHE | B | 403 | 43.480 | 69.429 | 48.824 | 1.00 | 18.46 | B | C |
| ATOM | 2413 | O | PHE | B | 403 | 42.787 | 70.134 | 49.554 | 1.00 | 19.46 | B | O |
| ATOM | 2414 | N | ALA | B | 404 | 44.712 | 69.059 | 49.141 | 1.00 | 17.78 | B | N |
| ATOM | 2415 | CA | ALA | B | 404 | 45.332 | 69.462 | 50.388 | 1.00 | 18.84 | B | C |
| ATOM | 2416 | CB | ALA | B | 404 | 46.725 | 68.873 | 50.482 | 1.00 | 16.08 | B | C |
| ATOM | 2417 | C | ALA | B | 404 | 45.398 | 70.981 | 50.459 | 1.00 | 19.17 | B | C |
| ATOM | 2418 | O | ALA | B | 404 | 44.973 | 71.590 | 51.440 | 1.00 | 20.06 | B | O |
| ATOM | 2419 | N | THR | B | 405 | 45.922 | 71.592 | 49.404 | 1.00 | 19.71 | B | N |
| ATOM | 2420 | CA | THR | B | 405 | 46.057 | 73.042 | 49.349 | 1.00 | 19.18 | B | C |
| ATOM | 2421 | CB | THR | B | 405 | 46.730 | 73.483 | 48.045 | 1.00 | 16.97 | B | C |
| ATOM | 2422 | OG1 | THR | B | 405 | 47.950 | 72.758 | 47.877 | 1.00 | 17.25 | B | O |
| ATOM | 2423 | CG2 | THR | B | 405 | 47.033 | 74.968 | 48.081 | 1.00 | 15.95 | B | C |
| ATOM | 2424 | C | THR | B | 405 | 44.743 | 73.800 | 49.489 | 1.00 | 20.57 | B | C |
| ATOM | 2425 | O | THR | B | 405 | 44.694 | 74.823 | 50.169 | 1.00 | 21.80 | B | O |
| ATOM | 2426 | N | ILE | B | 406 | 43.689 | 73.314 | 48.835 | 1.00 | 20.56 | B | N |
| ATOM | 2427 | CA | ILE | B | 406 | 42.381 | 73.969 | 48.913 | 1.00 | 21.70 | B | C |
| ATOM | 2428 | CB | ILE | B | 406 | 41.339 | 73.313 | 47.963 | 1.00 | 21.75 | B | C |
| ATOM | 2429 | CG2 | ILE | B | 406 | 39.959 | 73.911 | 48.210 | 1.00 | 21.34 | B | C |
| ATOM | 2430 | CG1 | ILE | B | 406 | 41.733 | 73.544 | 46.502 | 1.00 | 23.10 | B | C |
| ATOM | 2431 | CD1 | ILE | B | 406 | 40.994 | 72.654 | 45.517 | 1.00 | 23.78 | B | C |
| ATOM | 2432 | C | ILE | B | 406 | 41.857 | 73.860 | 50.342 | 1.00 | 21.98 | B | C |
| ATOM | 2433 | O | ILE | B | 406 | 41.372 | 74.839 | 50.916 | 1.00 | 22.44 | B | O |
| ATOM | 2434 | N | ILE | B | 407 | 41.963 | 72.662 | 50.910 | 1.00 | 22.06 | B | N |
| ATOM | 2435 | CA | ILE | B | 407 | 41.503 | 72.415 | 52.269 | 1.00 | 22.41 | B | C |
| ATOM | 2436 | CB | ILE | B | 407 | 41.703 | 70.943 | 52.656 | 1.00 | 21.46 | B | C |
| ATOM | 2437 | CG2 | ILE | B | 407 | 41.982 | 70.821 | 54.142 | 1.00 | 20.71 | B | C |
| ATOM | 2438 | CG1 | ILE | B | 407 | 40.456 | 70.145 | 52.292 | 1.00 | 19.88 | B | C |
| ATOM | 2439 | CD1 | ILE | B | 407 | 40.714 | 68.670 | 52.199 | 1.00 | 22.16 | B | C |
| ATOM | 2440 | C | ILE | B | 407 | 42.236 | 73.306 | 53.270 | 1.00 | 22.75 | B | C |
| ATOM | 2441 | O | ILE | B | 407 | 41.625 | 73.855 | 54.189 | 1.00 | 23.96 | B | O |
| ATOM | 2442 | N | LYS | B | 408 | 43.542 | 73.457 | 53.092 | 1.00 | 21.94 | B | N |
| ATOM | 2443 | CA | LYS | B | 408 | 44.313 | 74.294 | 54.001 | 1.00 | 21.96 | B | C |
| ATOM | 2444 | CB | LYS | B | 408 | 45.809 | 74.131 | 53.740 | 1.00 | 21.69 | B | C |
| ATOM | 2445 | CG | LYS | B | 408 | 46.399 | 72.909 | 54.425 | 1.00 | 23.63 | B | C |
| ATOM | 2446 | CD | LYS | B | 408 | 47.279 | 72.111 | 53.487 | 1.00 | 24.44 | B | C |
| ATOM | 2447 | CE | LYS | B | 408 | 48.728 | 72.499 | 53.656 | 1.00 | 26.02 | B | C |
| ATOM | 2448 | NZ | LYS | B | 408 | 48.967 | 73.112 | 54.992 | 1.00 | 27.54 | B | N |
| ATOM | 2449 | C | LYS | B | 408 | 43.913 | 75.759 | 53.874 | 1.00 | 22.49 | B | C |
| ATOM | 2450 | O | LYS | B | 408 | 43.985 | 76.520 | 54.846 | 1.00 | 22.42 | B | O |
| ATOM | 2451 | N | GLU | B | 409 | 43.480 | 76.148 | 52.680 | 1.00 | 20.72 | B | N |
| ATOM | 2452 | CA | GLU | B | 409 | 43.058 | 77.521 | 52.452 | 1.00 | 21.44 | B | C |
| ATOM | 2453 | CB | GLU | B | 409 | 42.946 | 77.794 | 50.951 | 1.00 | 21.82 | B | C |
| ATOM | 2454 | CG | GLU | B | 409 | 44.287 | 77.862 | 50.249 | 1.00 | 22.72 | B | C |
| ATOM | 2455 | CD | GLU | B | 409 | 44.167 | 78.231 | 48.782 | 1.00 | 24.03 | B | C |
| ATOM | 2456 | OE1 | GLU | B | 409 | 43.063 | 78.104 | 48.214 | 1.00 | 24.30 | B | O |
| ATOM | 2457 | OE2 | GLU | B | 409 | 45.186 | 78.646 | 48.194 | 1.00 | 26.48 | B | O |
| ATOM | 2458 | C | GLU | B | 409 | 41.713 | 77.759 | 53.135 | 1.00 | 20.29 | B | C |
| ATOM | 2459 | O | GLU | B | 409 | 41.420 | 78.863 | 53.598 | 1.00 | 20.65 | B | O |
| ATOM | 2460 | N | VAL | B | 410 | 40.893 | 76.719 | 53.185 | 1.00 | 20.00 | B | N |
| ATOM | 2461 | CA | VAL | B | 410 | 39.593 | 76.815 | 53.836 | 1.00 | 19.74 | B | C |
| ATOM | 2462 | CB | VAL | B | 410 | 38.748 | 75.554 | 53.586 | 1.00 | 18.95 | B | C |
| ATOM | 2463 | CG1 | VAL | B | 410 | 37.513 | 75.585 | 54.465 | 1.00 | 18.08 | B | C |
| ATOM | 2464 | CG2 | VAL | B | 410 | 38.364 | 75.462 | 52.105 | 1.00 | 16.64 | B | C |
| ATOM | 2465 | C | VAL | B | 410 | 39.826 | 76.956 | 55.344 | 1.00 | 21.00 | B | C |
| ATOM | 2466 | O | VAL | B | 410 | 39.251 | 77.828 | 55.994 | 1.00 | 20.22 | B | O |
| ATOM | 2467 | N | GLY | B | 411 | 40.686 | 76.093 | 55.884 | 1.00 | 22.09 | B | N |
| ATOM | 2468 | CA | GLY | B | 411 | 40.997 | 76.129 | 57.301 | 1.00 | 22.19 | B | C |
| ATOM | 2469 | C | GLY | B | 411 | 41.505 | 77.488 | 57.739 | 1.00 | 23.53 | B | C |
| ATOM | 2470 | O | GLY | B | 411 | 41.158 | 77.979 | 58.818 | 1.00 | 24.45 | B | O |
| ATOM | 2471 | N | ALA | B | 412 | 42.329 | 78.108 | 56.903 | 1.00 | 22.69 | B | N |
| ATOM | 2472 | CA | ALA | B | 412 | 42.873 | 79.418 | 57.222 | 1.00 | 22.69 | B | C |
| ATOM | 2473 | CB | ALA | B | 412 | 43.936 | 79.799 | 56.209 | 1.00 | 23.73 | B | C |
| ATOM | 2474 | C | ALA | B | 412 | 41.777 | 80.481 | 57.258 | 1.00 | 23.16 | B | C |
| ATOM | 2475 | O | ALA | B | 412 | 41.835 | 81.420 | 58.051 | 1.00 | 22.34 | B | O |
| ATOM | 2476 | N | ASP | B | 413 | 40.782 | 80.345 | 56.390 | 1.00 | 23.57 | B | N |
| ATOM | 2477 | CA | ASP | B | 413 | 39.681 | 81.305 | 56.367 | 1.00 | 24.14 | B | C |
| ATOM | 2478 | CB | ASP | B | 413 | 38.739 | 81.021 | 55.198 | 1.00 | 25.12 | B | C |
| ATOM | 2479 | CG | ASP | B | 413 | 39.250 | 81.576 | 53.882 | 1.00 | 25.96 | B | C |
| ATOM | 2480 | OD1 | ASP | B | 413 | 38.798 | 81.081 | 52.829 | 1.00 | 29.07 | B | O |
| ATOM | 2481 | OD2 | ASP | B | 413 | 40.092 | 82.499 | 53.895 | 1.00 | 25.15 | B | O |
| ATOM | 2482 | C | ASP | B | 413 | 38.909 | 81.164 | 57.673 | 1.00 | 24.76 | B | C |
| ATOM | 2483 | O | ASP | B | 413 | 38.402 | 82.142 | 58.224 | 1.00 | 24.74 | B | O |
| ATOM | 2484 | N | LEU | B | 414 | 38.822 | 79.925 | 58.149 | 1.00 | 24.28 | B | N |
| ATOM | 2485 | CA | LEU | B | 414 | 38.127 | 79.597 | 59.386 | 1.00 | 24.02 | B | C |
| ATOM | 2486 | CB | LEU | B | 414 | 38.128 | 78.077 | 59.591 | 1.00 | 23.10 | B | C |
| ATOM | 2487 | CG | LEU | B | 414 | 36.853 | 77.264 | 59.333 | 1.00 | 22.65 | B | C |
| ATOM | 2488 | CD1 | LEU | B | 414 | 35.887 | 78.023 | 58.457 | 1.00 | 21.81 | B | C |
| ATOM | 2489 | CD2 | LEU | B | 414 | 37.230 | 75.949 | 58.689 | 1.00 | 22.75 | B | C |
| ATOM | 2490 | C | LEU | B | 414 | 38.821 | 80.286 | 60.562 | 1.00 | 23.37 | B | C |
| ATOM | 2491 | O | LEU | B | 414 | 38.178 | 80.974 | 61.358 | 1.00 | 23.47 | B | O |
| ATOM | 2492 | N | VAL | B | 415 | 40.137 | 80.097 | 60.655 | 1.00 | 22.96 | B | N |
| ATOM | 2493 | CA | VAL | B | 415 | 40.938 | 80.695 | 61.716 | 1.00 | 22.49 | B | C |
| ATOM | 2494 | CB | VAL | B | 415 | 42.431 | 80.333 | 61.554 | 1.00 | 21.23 | B | C |
| ATOM | 2495 | CG1 | VAL | B | 415 | 43.283 | 81.191 | 62.464 | 1.00 | 20.82 | B | C |
| ATOM | 2496 | CG2 | VAL | B | 415 | 42.650 | 78.871 | 61.879 | 1.00 | 18.64 | B | C |
| ATOM | 2497 | C | VAL | B | 415 | 40.796 | 82.217 | 61.741 | 1.00 | 24.86 | B | C |
| ATOM | 2498 | O | VAL | B | 415 | 40.879 | 82.835 | 62.801 | 1.00 | 26.09 | B | O |
| ATOM | 2499 | N | ASP | B | 416 | 40.579 | 82.820 | 60.575 | 1.00 | 26.97 | B | N |
| ATOM | 2500 | CA | ASP | B | 416 | 40.420 | 84.269 | 60.475 | 1.00 | 27.82 | B | C |
| ATOM | 2501 | CB | ASP | B | 416 | 40.482 | 84.716 | 59.017 | 1.00 | 33.17 | B | C |
| ATOM | 2502 | CG | ASP | B | 416 | 41.894 | 84.958 | 58.541 | 1.00 | 38.40 | B | C |
| ATOM | 2503 | OD1 | ASP | B | 416 | 42.073 | 85.156 | 57.319 | 1.00 | 43.64 | B | O |
| ATOM | 2504 | OD2 | ASP | B | 416 | 42.822 | 84.948 | 59.382 | 1.00 | 41.36 | B | O |
| ATOM | 2505 | C | ASP | B | 416 | 39.096 | 84.728 | 61.060 | 1.00 | 26.18 | B | C |
| ATOM | 2506 | O | ASP | B | 416 | 39.017 | 85.785 | 61.677 | 1.00 | 25.43 | B | O |
| ATOM | 2507 | N | ALA | B | 417 | 38.052 | 83.935 | 60.848 | 1.00 | 25.55 | B | N |
| ATOM | 2508 | CA | ALA | B | 417 | 36.724 | 84.262 | 61.358 | 1.00 | 25.08 | B | C |
| ATOM | 2509 | CB | ALA | B | 417 | 35.672 | 83.501 | 60.575 | 1.00 | 26.21 | B | C |
| ATOM | 2510 | C | ALA | B | 417 | 36.639 | 83.911 | 62.840 | 1.00 | 23.14 | B | C |
| ATOM | 2511 | O | ALA | B | 417 | 35.757 | 84.381 | 63.553 | 1.00 | 23.56 | B | O |
| ATOM | 2512 | N | LYS | B | 418 | 37.550 | 83.048 | 63.275 | 1.00 | 23.12 | B | N |
| ATOM | 2513 | CA | LYS | B | 418 | 37.663 | 82.626 | 64.667 | 1.00 | 22.22 | B | C |
| ATOM | 2514 | CB | LYS | B | 418 | 37.913 | 83.855 | 65.550 | 1.00 | 21.96 | B | C |
| ATOM | 2515 | CG | LYS | B | 418 | 38.114 | 83.530 | 67.027 | 1.00 | 23.49 | B | C |
| ATOM | 2516 | CD | LYS | B | 418 | 38.292 | 84.797 | 67.848 | 1.00 | 25.29 | B | C |
| ATOM | 2517 | CE | LYS | B | 418 | 39.081 | 84.540 | 69.127 | 1.00 | 28.48 | B | C |
| ATOM | 2518 | NZ | LYS | B | 418 | 38.853 | 85.615 | 70.142 | 1.00 | 30.54 | B | N |
| ATOM | 2519 | C | LYS | B | 418 | 36.567 | 81.787 | 65.318 | 1.00 | 21.30 | B | C |
| ATOM | 2520 | O | LYS | B | 418 | 36.860 | 80.746 | 65.905 | 1.00 | 22.49 | B | O |
| ATOM | 2521 | N | TYR | B | 419 | 35.315 | 82.224 | 65.220 | 1.00 | 20.30 | B | N |
| ATOM | 2522 | CA | TYR | B | 419 | 34.227 | 81.527 | 65.900 | 1.00 | 20.41 | B | C |
| ATOM | 2523 | CB | TYR | B | 419 | 33.174 | 82.559 | 66.307 | 1.00 | 20.28 | B | C |
| ATOM | 2524 | CG | TYR | B | 419 | 33.792 | 83.675 | 67.106 | 1.00 | 21.53 | B | C |
| ATOM | 2525 | CD1 | TYR | B | 419 | 34.239 | 83.456 | 68.406 | 1.00 | 23.70 | B | C |
| ATOM | 2526 | CE1 | TYR | B | 419 | 34.897 | 84.455 | 69.122 | 1.00 | 25.21 | B | C |
| ATOM | 2527 | CD2 | TYR | B | 419 | 34.011 | 84.925 | 66.541 | 1.00 | 22.73 | B | C |
| ATOM | 2528 | CE2 | TYR | B | 419 | 34.669 | 85.932 | 67.248 | 1.00 | 24.02 | B | C |
| ATOM | 2529 | CZ | TYR | B | 419 | 35.111 | 85.686 | 68.536 | 1.00 | 25.20 | B | C |
| ATOM | 2530 | OH | TYR | B | 419 | 35.793 | 86.659 | 69.228 | 1.00 | 29.44 | B | O |
| ATOM | 2531 | C | TYR | B | 419 | 33.560 | 80.311 | 65.272 | 1.00 | 20.03 | B | C |
| ATOM | 2532 | O | TYR | B | 419 | 32.787 | 79.621 | 65.941 | 1.00 | 19.46 | B | O |
| ATOM | 2533 | N | GLN | B | 420 | 33.850 | 80.031 | 64.005 | 1.00 | 18.67 | B | N |
| ATOM | 2534 | CA | GLN | B | 420 | 33.262 | 78.867 | 63.350 | 1.00 | 18.21 | B | C |
| ATOM | 2535 | CB | GLN | B | 420 | 32.690 | 79.258 | 61.988 | 1.00 | 19.28 | B | C |
| ATOM | 2536 | CG | GLN | B | 420 | 31.345 | 79.957 | 62.069 | 1.00 | 23.95 | B | C |
| ATOM | 2537 | CD | GLN | B | 420 | 31.465 | 81.396 | 62.526 | 1.00 | 27.77 | B | C |
| ATOM | 2538 | OE1 | GLN | B | 420 | 30.927 | 81.780 | 63.570 | 1.00 | 29.82 | B | O |
| ATOM | 2539 | NE2 | GLN | B | 420 | 32.174 | 82.205 | 61.746 | 1.00 | 26.90 | B | N |
| ATOM | 2540 | C | GLN | B | 420 | 34.281 | 77.734 | 63.184 | 1.00 | 16.80 | B | C |
| ATOM | 2541 | O | GLN | B | 420 | 35.442 | 77.970 | 62.846 | 1.00 | 16.27 | B | O |
| ATOM | 2542 | N | HIS | B | 421 | 33.828 | 76.508 | 63.435 | 1.00 | 15.03 | B | N |
| ATOM | 2543 | CA | HIS | B | 421 | 34.656 | 75.311 | 63.322 | 1.00 | 14.22 | B | C |
| ATOM | 2544 | CB | HIS | B | 421 | 34.845 | 74.665 | 64.702 | 1.00 | 11.09 | B | C |
| ATOM | 2545 | CG | HIS | B | 421 | 35.586 | 75.530 | 65.675 | 1.00 | 10.94 | B | C |
| ATOM | 2546 | CD2 | HIS | B | 421 | 35.238 | 76.690 | 66.281 | 1.00 | 8.10 | B | C |
| ATOM | 2547 | ND1 | HIS | B | 421 | 36.870 | 75.249 | 66.094 | 1.00 | 10.64 | B | N |
| ATOM | 2548 | CE1 | HIS | B | 421 | 37.282 | 76.200 | 66.913 | 1.00 | 7.06 | B | C |
| ATOM | 2549 | NE2 | HIS | B | 421 | 36.310 | 77.085 | 67.043 | 1.00 | 8.55 | B | N |
| ATOM | 2550 | C | HIS | B | 421 | 33.946 | 74.334 | 62.391 | 1.00 | 15.06 | B | C |
| ATOM | 2551 | O | HIS | B | 421 | 32.764 | 74.527 | 62.079 | 1.00 | 14.79 | B | O |
| ATOM | 2552 | N | ALA | B | 422 | 34.651 | 73.286 | 61.956 | 1.00 | 15.35 | B | N |
| ATOM | 2553 | CA | ALA | B | 422 | 34.059 | 72.297 | 61.060 | 1.00 | 13.36 | B | C |
| ATOM | 2554 | CB | ALA | B | 422 | 34.297 | 72.707 | 59.609 | 1.00 | 13.79 | B | C |
| ATOM | 2555 | C | ALA | B | 422 | 34.606 | 70.894 | 61.295 | 1.00 | 13.52 | B | C |
| ATOM | 2556 | O | ALA | B | 422 | 35.756 | 70.730 | 61.699 | 1.00 | 13.88 | B | O |
| ATOM | 2557 | N | GLU | B | 423 | 33.775 | 69.884 | 61.029 | 1.00 | 13.01 | B | N |
| ATOM | 2558 | CA | GLU | B | 423 | 34.163 | 68.479 | 61.191 | 1.00 | 13.65 | B | C |
| ATOM | 2559 | CB | GLU | B | 423 | 33.202 | 67.777 | 62.157 | 1.00 | 13.11 | B | C |
| ATOM | 2560 | CG | GLU | B | 423 | 33.122 | 68.397 | 63.552 | 1.00 | 15.63 | B | C |
| ATOM | 2561 | CD | GLU | B | 423 | 32.395 | 67.493 | 64.536 | 1.00 | 16.90 | B | C |
| ATOM | 2562 | OE1 | GLU | B | 423 | 33.063 | 66.663 | 65.197 | 1.00 | 17.68 | B | O |
| ATOM | 2563 | OE2 | GLU | B | 423 | 31.153 | 67.606 | 64.638 | 1.00 | 19.35 | B | O |
| ATOM | 2564 | C | GLU | B | 423 | 34.148 | 67.748 | 59.833 | 1.00 | 13.68 | B | C |
| ATOM | 2565 | O | GLU | B | 423 | 33.324 | 66.851 | 59.595 | 1.00 | 11.74 | B | O |
| ATOM | 2566 | N | PRO | B | 424 | 35.066 | 68.124 | 58.927 | 1.00 | 14.55 | B | N |
| ATOM | 2567 | CD | PRO | B | 424 | 36.080 | 69.182 | 59.093 | 1.00 | 12.87 | B | C |
| ATOM | 2568 | CA | PRO | B | 424 | 35.131 | 67.495 | 57.603 | 1.00 | 14.87 | B | C |
| ATOM | 2569 | CB | PRO | B | 424 | 36.240 | 68.268 | 56.889 | 1.00 | 14.60 | B | C |
| ATOM | 2570 | CG | PRO | B | 424 | 37.010 | 68.943 | 57.966 | 1.00 | 15.32 | B | C |
| ATOM | 2571 | C | PRO | B | 424 | 35.368 | 65.990 | 57.586 | 1.00 | 16.05 | B | C |
| ATOM | 2572 | O | PRO | B | 424 | 36.217 | 65.470 | 58.302 | 1.00 | 16.95 | B | O |
| ATOM | 2573 | N | ARG | B | 425 | 34.606 | 65.300 | 56.743 | 1.00 | 16.81 | B | N |
| ATOM | 2574 | CA | ARG | B | 425 | 34.701 | 63.852 | 56.598 | 1.00 | 16.74 | B | C |
| ATOM | 2575 | CB | ARG | B | 425 | 33.285 | 63.260 | 56.435 | 1.00 | 16.29 | B | C |
| ATOM | 2576 | CG | ARG | B | 425 | 32.787 | 62.468 | 57.649 | 1.00 | 17.07 | B | C |
| ATOM | 2577 | CD | ARG | B | 425 | 31.452 | 62.970 | 58.212 | 1.00 | 17.37 | B | C |
| ATOM | 2578 | NE | ARG | B | 425 | 31.595 | 64.230 | 58.931 | 1.00 | 18.24 | B | N |
| ATOM | 2579 | CZ | ARG | B | 425 | 30.782 | 64.667 | 59.894 | 1.00 | 16.41 | B | C |
| ATOM | 2580 | NH1 | ARG | B | 425 | 29.730 | 63.956 | 60.293 | 1.00 | 10.63 | B | N |
| ATOM | 2581 | NH2 | ARG | B | 425 | 31.019 | 65.846 | 60.451 | 1.00 | 15.95 | B | N |
| ATOM | 2582 | C | ARG | B | 425 | 35.582 | 63.465 | 55.398 | 1.00 | 17.33 | B | C |
| ATOM | 2583 | O | ARG | B | 425 | 35.382 | 63.961 | 54.288 | 1.00 | 16.89 | B | O |
| ATOM | 2584 | N | LEU | B | 426 | 36.567 | 62.599 | 55.642 | 1.00 | 17.13 | B | N |
| ATOM | 2585 | CA | LEU | B | 426 | 37.482 | 62.111 | 54.605 | 1.00 | 16.46 | B | C |
| ATOM | 2586 | CB | LEU | B | 426 | 38.932 | 62.106 | 55.103 | 1.00 | 14.89 | B | C |
| ATOM | 2587 | CG | LEU | B | 426 | 39.635 | 63.446 | 55.320 | 1.00 | 15.63 | B | C |
| ATOM | 2588 | CD1 | LEU | B | 426 | 40.964 | 63.235 | 56.048 | 1.00 | 13.46 | B | C |
| ATOM | 2589 | CD2 | LEU | B | 426 | 39.859 | 64.118 | 53.975 | 1.00 | 13.65 | B | C |
| ATOM | 2590 | C | LEU | B | 426 | 37.055 | 60.683 | 54.287 | 1.00 | 17.44 | B | C |
| ATOM | 2591 | O | LEU | B | 426 | 36.466 | 60.009 | 55.136 | 1.00 | 17.34 | B | O |
| ATOM | 2592 | N | SER | B | 427 | 37.366 | 60.213 | 53.079 | 1.00 | 16.36 | B | N |
| ATOM | 2593 | CA | SER | B | 427 | 36.955 | 58.872 | 52.664 | 1.00 | 17.94 | B | C |
| ATOM | 2594 | CB | SER | B | 427 | 36.421 | 58.902 | 51.226 | 1.00 | 17.38 | B | C |
| ATOM | 2595 | OG | SER | B | 427 | 35.343 | 59.804 | 51.091 | 1.00 | 18.21 | B | O |
| ATOM | 2596 | C | SER | B | 427 | 37.969 | 57.743 | 52.745 | 1.00 | 17.81 | B | C |
| ATOM | 2597 | O | SER | B | 427 | 39.133 | 57.906 | 52.403 | 1.00 | 17.94 | B | O |
| ATOM | 2598 | N | ILE | B | 428 | 37.483 | 56.593 | 53.201 | 1.00 | 18.88 | B | N |
| ATOM | 2599 | CA | ILE | B | 428 | 38.250 | 55.355 | 53.291 | 1.00 | 19.33 | B | C |
| ATOM | 2600 | CB | ILE | B | 428 | 38.613 | 54.987 | 54.752 | 1.00 | 17.61 | B | C |
| ATOM | 2601 | CG2 | ILE | B | 428 | 38.941 | 53.501 | 54.852 | 1.00 | 15.11 | B | C |
| ATOM | 2602 | CG1 | ILE | B | 428 | 39.813 | 55.823 | 55.211 | 1.00 | 14.66 | B | C |
| ATOM | 2603 | CD1 | ILE | B | 428 | 41.144 | 55.444 | 54.571 | 1.00 | 14.51 | B | C |
| ATOM | 2604 | C | ILE | B | 428 | 37.205 | 54.390 | 52.743 | 1.00 | 20.43 | B | C |
| ATOM | 2605 | O | ILE | B | 428 | 36.132 | 54.249 | 53.331 | 1.00 | 20.96 | B | O |
| ATOM | 2606 | N | TYR | B | 429 | 37.504 | 53.743 | 51.616 | 1.00 | 20.77 | B | N |
| ATOM | 2607 | CA | TYR | B | 429 | 36.538 | 52.854 | 50.961 | 1.00 | 21.03 | B | C |
| ATOM | 2608 | CB | TYR | B | 429 | 36.662 | 52.985 | 49.442 | 1.00 | 20.20 | B | C |
| ATOM | 2609 | CG | TYR | B | 429 | 36.660 | 54.408 | 48.946 | 1.00 | 18.35 | B | C |
| ATOM | 2610 | CD1 | TYR | B | 429 | 37.837 | 55.143 | 48.885 | 1.00 | 19.89 | B | C |
| ATOM | 2611 | CE1 | TYR | B | 429 | 37.836 | 56.462 | 48.439 | 1.00 | 18.73 | B | C |
| ATOM | 2612 | CD2 | TYR | B | 429 | 35.473 | 55.026 | 48.548 | 1.00 | 18.20 | B | C |
| ATOM | 2613 | CE2 | TYR | B | 429 | 35.461 | 56.339 | 48.103 | 1.00 | 16.66 | B | C |
| ATOM | 2614 | CZ | TYR | B | 429 | 36.647 | 57.048 | 48.052 | 1.00 | 19.08 | B | C |
| ATOM | 2615 | OH | TYR | B | 429 | 36.650 | 58.347 | 47.604 | 1.00 | 24.42 | B | O |
| ATOM | 2616 | C | TYR | B | 429 | 36.539 | 51.376 | 51.290 | 1.00 | 22.34 | B | C |
| ATOM | 2617 | O | TYR | B | 429 | 35.524 | 50.709 | 51.099 | 1.00 | 23.15 | B | O |
| ATOM | 2618 | N | GLY | B | 430 | 37.661 | 50.852 | 51.764 | 1.00 | 23.60 | B | N |
| ATOM | 2619 | CA | GLY | B | 430 | 37.714 | 49.430 | 52.050 | 1.00 | 24.26 | B | C |
| ATOM | 2620 | C | GLY | B | 430 | 37.914 | 48.681 | 50.742 | 1.00 | 24.88 | B | C |
| ATOM | 2621 | O | GLY | B | 430 | 37.615 | 47.494 | 50.632 | 1.00 | 24.20 | B | O |
| ATOM | 2622 | N | ARG | B | 431 | 38.415 | 49.398 | 49.740 | 1.00 | 26.40 | B | N |
| ATOM | 2623 | CA | ARG | B | 431 | 38.676 | 48.830 | 48.423 | 1.00 | 27.31 | B | C |
| ATOM | 2624 | CB | ARG | B | 431 | 38.599 | 49.926 | 47.359 | 1.00 | 29.34 | B | C |
| ATOM | 2625 | CG | ARG | B | 431 | 38.751 | 49.435 | 45.923 | 1.00 | 32.52 | B | C |
| ATOM | 2626 | CD | ARG | B | 431 | 39.175 | 50.573 | 45.001 | 1.00 | 33.15 | B | C |
| ATOM | 2627 | NE | ARG | B | 431 | 40.406 | 51.208 | 45.463 | 1.00 | 35.64 | B | N |
| ATOM | 2628 | CZ | ARG | B | 431 | 40.489 | 52.460 | 45.903 | 1.00 | 36.22 | B | C |
| ATOM | 2629 | NH1 | ARG | B | 431 | 39.407 | 53.229 | 45.946 | 1.00 | 37.36 | B | N |
| ATOM | 2630 | NH2 | ARG | B | 431 | 41.658 | 52.945 | 46.299 | 1.00 | 35.20 | B | N |
| ATOM | 2631 | C | ARG | B | 431 | 40.069 | 48.224 | 48.441 | 1.00 | 26.78 | B | C |
| ATOM | 2632 | O | ARG | B | 431 | 40.309 | 47.185 | 47.840 | 1.00 | 26.89 | B | O |
| ATOM | 2633 | N | SER | B | 432 | 40.983 | 48.881 | 49.146 | 1.00 | 27.85 | B | N |
| ATOM | 2634 | CA | SER | B | 432 | 42.358 | 48.414 | 49.259 | 1.00 | 29.57 | B | C |
| ATOM | 2635 | CB | SER | B | 432 | 43.251 | 49.159 | 48.270 | 1.00 | 28.82 | B | C |
| ATOM | 2636 | OG | SER | B | 432 | 44.613 | 48.951 | 48.582 | 1.00 | 29.27 | B | O |
| ATOM | 2637 | C | SER | B | 432 | 42.876 | 48.628 | 50.682 | 1.00 | 31.22 | B | C |
| ATOM | 2638 | O | SER | B | 432 | 42.516 | 49.601 | 51.344 | 1.00 | 31.01 | B | O |
| ATOM | 2639 | N | PRO | B | 433 | 43.745 | 47.723 | 51.166 | 1.00 | 32.15 | B | N |
| ATOM | 2640 | CD | PRO | B | 433 | 44.258 | 46.545 | 50.442 | 1.00 | 32.99 | B | C |
| ATOM | 2641 | CA | PRO | B | 433 | 44.306 | 47.820 | 52.521 | 1.00 | 31.74 | B | C |
| ATOM | 2642 | CB | PRO | B | 433 | 44.907 | 46.438 | 52.759 | 1.00 | 31.41 | B | C |
| ATOM | 2643 | CG | PRO | B | 433 | 45.282 | 45.966 | 51.395 | 1.00 | 32.43 | B | C |
| ATOM | 2644 | C | PRO | B | 433 | 45.338 | 48.931 | 52.709 | 1.00 | 31.87 | B | C |
| ATOM | 2645 | O | PRO | B | 433 | 45.646 | 49.313 | 53.838 | 1.00 | 31.86 | B | O |
| ATOM | 2646 | N | ASP | B | 434 | 45.870 | 49.453 | 51.608 | 1.00 | 31.30 | B | N |
| ATOM | 2647 | CA | ASP | B | 434 | 46.868 | 50.512 | 51.696 | 1.00 | 30.59 | B | C |
| ATOM | 2648 | CB | ASP | B | 434 | 47.874 | 50.378 | 50.542 | 1.00 | 35.98 | B | C |
| ATOM | 2649 | CG | ASP | B | 434 | 47.344 | 50.937 | 49.226 | 1.00 | 41.62 | B | C |
| ATOM | 2650 | OD1 | ASP | B | 434 | 46.107 | 50.968 | 49.030 | 1.00 | 43.98 | B | O |
| ATOM | 2651 | OD2 | ASP | B | 434 | 48.172 | 51.347 | 48.380 | 1.00 | 44.03 | B | O |
| ATOM | 2652 | C | ASP | B | 434 | 46.266 | 51.921 | 51.717 | 1.00 | 27.95 | B | C |
| ATOM | 2653 | O | ASP | B | 434 | 46.999 | 52.913 | 51.717 | 1.00 | 26.50 | B | O |
| ATOM | 2654 | N | GLU | B | 435 | 44.938 | 52.008 | 51.747 | 1.00 | 24.19 | B | N |
| ATOM | 2655 | CA | GLU | B | 435 | 44.257 | 53.303 | 51.763 | 1.00 | 23.19 | B | C |
| ATOM | 2656 | CB | GLU | B | 435 | 42.747 | 53.093 | 51.711 | 1.00 | 22.97 | B | C |
| ATOM | 2657 | CG | GLU | B | 435 | 42.256 | 52.521 | 50.397 | 1.00 | 22.73 | B | C |
| ATOM | 2658 | CD | GLU | B | 435 | 40.751 | 52.586 | 50.259 | 1.00 | 22.27 | B | C |
| ATOM | 2659 | OE1 | GLU | B | 435 | 40.148 | 51.550 | 49.915 | 1.00 | 22.18 | B | O |
| ATOM | 2660 | OE2 | GLU | B | 435 | 40.169 | 53.670 | 50.490 | 1.00 | 24.80 | B | O |
| ATOM | 2661 | C | GLU | B | 435 | 44.615 | 54.139 | 52.993 | 1.00 | 23.05 | B | C |
| ATOM | 2662 | O | GLU | B | 435 | 44.831 | 55.350 | 52.905 | 1.00 | 22.60 | B | O |
| ATOM | 2663 | N | TRP | B | 436 | 44.674 | 53.483 | 54.147 | 1.00 | 23.70 | B | N |
| ATOM | 2664 | CA | TRP | B | 436 | 45.008 | 54.159 | 55.395 | 1.00 | 21.63 | B | C |
| ATOM | 2665 | CB | TRP | B | 436 | 44.863 | 53.179 | 56.567 | 1.00 | 19.94 | B | C |
| ATOM | 2666 | CG | TRP | B | 436 | 43.436 | 53.009 | 57.038 | 1.00 | 17.20 | B | C |
| ATOM | 2667 | CD2 | TRP | B | 436 | 42.673 | 53.941 | 57.819 | 1.00 | 14.91 | B | C |
| ATOM | 2668 | CE2 | TRP | B | 436 | 41.406 | 53.355 | 58.052 | 1.00 | 15.79 | B | C |
| ATOM | 2669 | CE3 | TRP | B | 436 | 42.938 | 55.210 | 58.347 | 1.00 | 14.90 | B | C |
| ATOM | 2670 | CD1 | TRP | B | 436 | 42.621 | 51.928 | 56.830 | 1.00 | 16.02 | B | C |
| ATOM | 2671 | NE1 | TRP | B | 436 | 41.399 | 52.128 | 57.437 | 1.00 | 14.07 | B | N |
| ATOM | 2672 | CZ2 | TRP | B | 436 | 40.408 | 53.999 | 58.791 | 1.00 | 14.97 | B | C |
| ATOM | 2673 | CZ3 | TRP | B | 436 | 41.947 | 55.848 | 59.082 | 1.00 | 14.90 | B | C |
| ATOM | 2674 | CH2 | TRP | B | 436 | 40.698 | 55.239 | 59.297 | 1.00 | 14.68 | B | C |
| ATOM | 2675 | C | TRP | B | 436 | 46.434 | 54.689 | 55.317 | 1.00 | 21.14 | B | C |
| ATOM | 2676 | O | TRP | B | 436 | 46.715 | 55.828 | 55.697 | 1.00 | 21.25 | B | O |
| ATOM | 2677 | N | SER | B | 437 | 47.336 | 53.859 | 54.809 | 1.00 | 22.17 | B | N |
| ATOM | 2678 | CA | SER | B | 437 | 48.728 | 54.259 | 54.675 | 1.00 | 23.73 | B | C |
| ATOM | 2679 | CB | SER | B | 437 | 49.556 | 53.117 | 54.093 | 1.00 | 23.90 | B | C |
| ATOM | 2680 | OG | SER | B | 437 | 50.781 | 53.620 | 53.587 | 1.00 | 27.14 | B | O |
| ATOM | 2681 | C | SER | B | 437 | 48.862 | 55.477 | 53.767 | 1.00 | 23.51 | B | C |
| ATOM | 2682 | O | SER | B | 437 | 49.644 | 56.385 | 54.040 | 1.00 | 24.40 | B | O |
| ATOM | 2683 | N | LYS | B | 438 | 48.099 | 55.485 | 52.680 | 1.00 | 22.68 | B | N |
| ATOM | 2684 | CA | LYS | B | 438 | 48.138 | 56.585 | 51.727 | 1.00 | 22.91 | B | C |
| ATOM | 2685 | CB | LYS | B | 438 | 47.396 | 56.194 | 50.445 | 1.00 | 24.90 | B | C |
| ATOM | 2686 | CG | LYS | B | 438 | 48.042 | 55.066 | 49.657 | 1.00 | 25.77 | B | C |
| ATOM | 2687 | CD | LYS | B | 438 | 48.086 | 55.406 | 48.182 | 1.00 | 28.06 | B | C |
| ATOM | 2688 | CE | LYS | B | 438 | 47.783 | 54.191 | 47.315 | 1.00 | 31.11 | B | C |
| ATOM | 2689 | NZ | LYS | B | 438 | 47.929 | 54.503 | 45.868 | 1.00 | 31.34 | B | N |
| ATOM | 2690 | C | LYS | B | 438 | 47.525 | 57.861 | 52.288 | 1.00 | 21.38 | B | C |
| ATOM | 2691 | O | LYS | B | 438 | 48.093 | 58.946 | 52.148 | 1.00 | 22.43 | B | O |
| ATOM | 2692 | N | LEU | B | 439 | 46.362 | 57.728 | 52.921 | 1.00 | 21.03 | B | N |
| ATOM | 2693 | CA | LEU | B | 439 | 45.662 | 58.878 | 53.487 | 1.00 | 18.55 | B | C |
| ATOM | 2694 | CB | LEU | B | 439 | 44.268 | 58.467 | 53.969 | 1.00 | 16.98 | B | C |
| ATOM | 2695 | CG | LEU | B | 439 | 43.330 | 59.588 | 54.428 | 1.00 | 16.26 | B | C |
| ATOM | 2696 | CD1 | LEU | B | 439 | 43.324 | 60.738 | 53.422 | 1.00 | 15.73 | B | C |
| ATOM | 2697 | CD2 | LEU | B | 439 | 41.927 | 59.020 | 54.599 | 1.00 | 15.96 | B | C |
| ATOM | 2698 | C | LEU | B | 439 | 46.434 | 59.514 | 54.629 | 1.00 | 19.28 | B | C |
| ATOM | 2699 | O | LEU | B | 439 | 46.541 | 60.738 | 54.698 | 1.00 | 20.24 | B | O |
| ATOM | 2700 | N | SER | B | 440 | 46.980 | 58.690 | 55.520 | 1.00 | 18.49 | B | N |
| ATOM | 2701 | CA | SER | B | 440 | 47.734 | 59.210 | 56.651 | 1.00 | 19.13 | B | C |
| ATOM | 2702 | CB | SER | B | 440 | 48.180 | 58.074 | 57.582 | 1.00 | 20.22 | B | C |
| ATOM | 2703 | OG | SER | B | 440 | 49.063 | 57.175 | 56.941 | 1.00 | 22.56 | B | O |
| ATOM | 2704 | C | SER | B | 440 | 48.934 | 60.003 | 56.166 | 1.00 | 19.57 | B | C |
| ATOM | 2705 | O | SER | B | 440 | 49.248 | 61.055 | 56.722 | 1.00 | 19.24 | B | O |
| ATOM | 2706 | N | SER | B | 441 | 49.596 | 59.505 | 55.123 | 1.00 | 21.52 | B | N |
| ATOM | 2707 | CA | SER | B | 441 | 50.759 | 60.188 | 54.545 | 1.00 | 23.23 | B | C |
| ATOM | 2708 | CB | SER | B | 441 | 51.429 | 59.304 | 53.487 | 1.00 | 22.86 | B | C |
| ATOM | 2709 | OG | SER | B | 441 | 51.844 | 58.067 | 54.037 | 1.00 | 24.49 | B | O |
| ATOM | 2710 | C | SER | B | 441 | 50.328 | 61.510 | 53.904 | 1.00 | 21.79 | B | C |
| ATOM | 2711 | O | SER | B | 441 | 51.033 | 62.517 | 53.992 | 1.00 | 21.13 | B | O |
| ATOM | 2712 | N | TRP | B | 442 | 49.167 | 61.497 | 53.253 | 1.00 | 22.74 | B | N |
| ATOM | 2713 | CA | TRP | B | 442 | 48.638 | 62.698 | 52.613 | 1.00 | 21.49 | B | C |
| ATOM | 2714 | CB | TRP | B | 442 | 47.320 | 62.374 | 51.893 | 1.00 | 20.76 | B | C |
| ATOM | 2715 | CG | TRP | B | 442 | 46.577 | 63.579 | 51.368 | 1.00 | 22.46 | B | C |
| ATOM | 2716 | CD2 | TRP | B | 442 | 45.468 | 64.249 | 51.991 | 1.00 | 24.54 | B | C |
| ATOM | 2717 | CE2 | TRP | B | 442 | 45.098 | 65.324 | 51.144 | 1.00 | 23.35 | B | C |
| ATOM | 2718 | CE3 | TRP | B | 442 | 44.751 | 64.046 | 53.182 | 1.00 | 23.33 | B | C |
| ATOM | 2719 | CD1 | TRP | B | 442 | 46.825 | 64.256 | 50.205 | 1.00 | 21.79 | B | C |
| ATOM | 2720 | NE1 | TRP | B | 442 | 45.941 | 65.304 | 50.065 | 1.00 | 22.48 | B | N |
| ATOM | 2721 | CZ2 | TRP | B | 442 | 44.043 | 66.196 | 51.450 | 1.00 | 23.79 | B | C |
| ATOM | 2722 | CZ3 | TRP | B | 442 | 43.701 | 64.919 | 53.486 | 1.00 | 24.76 | B | C |
| ATOM | 2723 | CH2 | TRP | B | 442 | 43.359 | 65.978 | 52.620 | 1.00 | 23.62 | B | C |
| ATOM | 2724 | C | TRP | B | 442 | 48.407 | 63.759 | 53.687 | 1.00 | 22.43 | B | C |
| ATOM | 2725 | O | TRP | B | 442 | 48.820 | 64.912 | 53.547 | 1.00 | 21.98 | B | O |
| ATOM | 2726 | N | PHE | B | 443 | 47.756 | 63.349 | 54.768 | 1.00 | 22.75 | B | N |
| ATOM | 2727 | CA | PHE | B | 443 | 47.442 | 64.243 | 55.878 | 1.00 | 23.93 | B | C |
| ATOM | 2728 | CB | PHE | B | 443 | 46.562 | 63.495 | 56.891 | 1.00 | 24.14 | B | C |
| ATOM | 2729 | CG | PHE | B | 443 | 45.894 | 64.387 | 57.896 | 1.00 | 23.97 | B | C |
| ATOM | 2730 | CD1 | PHE | B | 443 | 46.549 | 64.747 | 59.069 | 1.00 | 24.17 | B | C |
| ATOM | 2731 | CD2 | PHE | B | 443 | 44.605 | 64.858 | 57.678 | 1.00 | 24.04 | B | C |
| ATOM | 2732 | CE1 | PHE | B | 443 | 45.926 | 65.566 | 60.013 | 1.00 | 23.64 | B | C |
| ATOM | 2733 | CE2 | PHE | B | 443 | 43.977 | 65.675 | 58.616 | 1.00 | 23.82 | B | C |
| ATOM | 2734 | CZ | PHE | B | 443 | 44.639 | 66.028 | 59.783 | 1.00 | 23.12 | B | C |
| ATOM | 2735 | C | PHE | B | 443 | 48.686 | 64.794 | 56.580 | 1.00 | 23.89 | B | C |
| ATOM | 2736 | O | PHE | B | 443 | 48.813 | 66.002 | 56.780 | 1.00 | 23.61 | B | O |
| ATOM | 2737 | N | VAL | B | 444 | 49.597 | 63.899 | 56.953 | 1.00 | 24.52 | B | N |
| ATOM | 2738 | CA | VAL | B | 444 | 50.819 | 64.282 | 57.653 | 1.00 | 24.59 | B | C |
| ATOM | 2739 | CB | VAL | B | 444 | 51.554 | 63.042 | 58.185 | 1.00 | 24.52 | B | C |
| ATOM | 2740 | CG1 | VAL | B | 444 | 52.809 | 63.458 | 58.914 | 1.00 | 25.78 | B | C |
| ATOM | 2741 | CG2 | VAL | B | 444 | 50.642 | 62.257 | 59.115 | 1.00 | 26.66 | B | C |
| ATOM | 2742 | C | VAL | B | 444 | 51.789 | 65.086 | 56.796 | 1.00 | 25.99 | B | C |
| ATOM | 2743 | O | VAL | B | 444 | 52.201 | 66.182 | 57.172 | 1.00 | 25.17 | B | O |
| ATOM | 2744 | N | ARG | B | 445 | 52.151 | 64.540 | 55.642 | 1.00 | 27.19 | B | N |
| ATOM | 2745 | CA | ARG | B | 445 | 53.081 | 65.211 | 54.749 | 1.00 | 29.18 | B | C |
| ATOM | 2746 | CB | ARG | B | 445 | 53.359 | 64.326 | 53.533 | 1.00 | 31.80 | B | C |
| ATOM | 2747 | CG | ARG | B | 445 | 54.512 | 63.356 | 53.745 | 1.00 | 37.23 | B | C |
| ATOM | 2748 | CD | ARG | B | 445 | 54.234 | 62.002 | 53.118 | 1.00 | 40.93 | B | C |
| ATOM | 2749 | NE | ARG | B | 445 | 55.079 | 60.953 | 53.684 | 1.00 | 44.06 | B | N |
| ATOM | 2750 | CZ | ARG | B | 445 | 55.585 | 59.944 | 52.980 | 1.00 | 47.25 | B | C |
| ATOM | 2751 | NH1 | ARG | B | 445 | 55.332 | 59.845 | 51.680 | 1.00 | 46.96 | B | N |
| ATOM | 2752 | NH2 | ARG | B | 445 | 56.347 | 59.034 | 53.574 | 1.00 | 46.70 | B | N |
| ATOM | 2753 | C | ARG | B | 445 | 52.617 | 66.594 | 54.293 | 1.00 | 28.76 | B | C |
| ATOM | 2754 | O | ARG | B | 445 | 53.437 | 67.482 | 54.064 | 1.00 | 29.32 | B | O |
| ATOM | 2755 | N | ASN | B | 446 | 51.311 | 66.789 | 54.163 | 1.00 | 27.42 | B | N |
| ATOM | 2756 | CA | ASN | B | 446 | 50.804 | 68.084 | 53.723 | 1.00 | 26.20 | B | C |
| ATOM | 2757 | CB | ASN | B | 446 | 49.531 | 67.905 | 52.895 | 1.00 | 25.35 | B | C |
| ATOM | 2758 | CG | ASN | B | 446 | 49.823 | 67.484 | 51.468 | 1.00 | 24.44 | B | C |
| ATOM | 2759 | OD1 | ASN | B | 446 | 49.643 | 66.324 | 51.104 | 1.00 | 24.52 | B | O |
| ATOM | 2760 | ND2 | ASN | B | 446 | 50.280 | 68.427 | 50.654 | 1.00 | 24.56 | B | N |
| ATOM | 2761 | C | ASN | B | 446 | 50.530 | 68.992 | 54.910 | 1.00 | 27.33 | B | C |
| ATOM | 2762 | O | ASN | B | 446 | 50.058 | 70.120 | 54.745 | 1.00 | 25.80 | B | O |
| ATOM | 2763 | N | ARG | B | 447 | 50.839 | 68.490 | 56.104 | 1.00 | 27.97 | B | N |
| ATOM | 2764 | CA | ARG | B | 447 | 50.632 | 69.235 | 57.343 | 1.00 | 29.47 | B | C |
| ATOM | 2765 | CB | ARG | B | 447 | 51.651 | 70.375 | 57.469 | 1.00 | 30.74 | B | C |
| ATOM | 2766 | CG | ARG | B | 447 | 53.044 | 70.028 | 56.976 | 1.00 | 35.57 | B | C |
| ATOM | 2767 | CD | ARG | B | 447 | 53.955 | 69.581 | 58.114 | 1.00 | 39.55 | B | C |
| ATOM | 2768 | NE | ARG | B | 447 | 54.106 | 70.623 | 59.127 | 1.00 | 44.32 | B | N |
| ATOM | 2769 | CZ | ARG | B | 447 | 54.462 | 70.397 | 60.388 | 1.00 | 44.53 | B | C |
| ATOM | 2770 | NH1 | ARG | B | 447 | 54.707 | 69.161 | 60.801 | 1.00 | 45.13 | B | N |
| ATOM | 2771 | NH2 | ARG | B | 447 | 54.568 | 71.407 | 61.238 | 1.00 | 47.17 | B | N |
| ATOM | 2772 | C | ARG | B | 447 | 49.226 | 69.806 | 57.383 | 1.00 | 29.42 | B | C |
| ATOM | 2773 | O | ARG | B | 447 | 49.039 | 71.008 | 57.572 | 1.00 | 28.82 | B | O |
| ATOM | 2774 | N | ILE | B | 448 | 48.237 | 68.942 | 57.192 | 1.00 | 28.94 | B | N |
| ATOM | 2775 | CA | ILE | B | 448 | 46.854 | 69.379 | 57.216 | 1.00 | 29.89 | B | C |
| ATOM | 2776 | CB | ILE | B | 448 | 45.955 | 68.426 | 56.398 | 1.00 | 29.92 | B | C |
| ATOM | 2777 | CG2 | ILE | B | 448 | 44.495 | 68.670 | 56.716 | 1.00 | 30.11 | B | C |
| ATOM | 2778 | CG1 | ILE | B | 448 | 46.190 | 68.648 | 54.906 | 1.00 | 29.75 | B | C |
| ATOM | 2779 | CD1 | ILE | B | 448 | 46.078 | 67.390 | 54.113 | 1.00 | 30.34 | B | C |
| ATOM | 2780 | C | ILE | B | 448 | 46.401 | 69.403 | 58.669 | 1.00 | 30.36 | B | C |
| ATOM | 2781 | O | ILE | B | 448 | 46.125 | 68.370 | 59.266 | 1.00 | 33.76 | B | O |
| ATOM | 2782 | N | TYR | B | 449 | 46.359 | 70.591 | 59.246 | 1.00 | 29.97 | B | N |
| ATOM | 2783 | CA | TYR | B | 449 | 45.940 | 70.749 | 60.628 | 1.00 | 28.50 | B | C |
| ATOM | 2784 | CB | TYR | B | 449 | 47.074 | 70.383 | 61.598 | 1.00 | 28.91 | B | C |
| ATOM | 2785 | CG | TYR | B | 449 | 46.827 | 70.925 | 62.987 | 1.00 | 30.79 | B | C |
| ATOM | 2786 | CD1 | TYR | B | 449 | 46.065 | 70.210 | 63.908 | 1.00 | 31.76 | B | C |
| ATOM | 2787 | CE1 | TYR | B | 449 | 45.722 | 70.763 | 65.143 | 1.00 | 32.60 | B | C |
| ATOM | 2788 | CD2 | TYR | B | 449 | 47.254 | 72.205 | 63.341 | 1.00 | 32.01 | B | C |
| ATOM | 2789 | CE2 | TYR | B | 449 | 46.916 | 72.765 | 64.569 | 1.00 | 32.81 | B | C |
| ATOM | 2790 | CZ | TYR | B | 449 | 46.147 | 72.043 | 65.462 | 1.00 | 33.13 | B | C |
| ATOM | 2791 | OH | TYR | B | 449 | 45.784 | 72.616 | 66.660 | 1.00 | 36.52 | B | O |
| ATOM | 2792 | C | TYR | B | 449 | 45.540 | 72.201 | 60.839 | 1.00 | 27.24 | B | C |
| ATOM | 2793 | O | TYR | B | 449 | 46.335 | 73.111 | 60.617 | 1.00 | 28.50 | B | O |
| ATOM | 2794 | N | SER | B | 450 | 44.299 | 72.414 | 61.253 | 1.00 | 25.17 | B | N |
| ATOM | 2795 | CA | SER | B | 450 | 43.803 | 73.758 | 61.499 | 1.00 | 24.38 | B | C |
| ATOM | 2796 | CB | SER | B | 450 | 42.696 | 74.121 | 60.504 | 1.00 | 22.91 | B | C |
| ATOM | 2797 | OG | SER | B | 450 | 41.953 | 75.258 | 60.935 | 1.00 | 23.17 | B | O |
| ATOM | 2798 | C | SER | B | 450 | 43.249 | 73.758 | 62.910 | 1.00 | 24.79 | B | C |
| ATOM | 2799 | O | SER | B | 450 | 42.707 | 72.753 | 63.379 | 1.00 | 25.40 | B | O |
| ATOM | 2800 | N | SER | B | 451 | 43.397 | 74.877 | 63.599 | 1.00 | 23.77 | B | N |
| ATOM | 2801 | CA | SER | B | 451 | 42.889 | 74.960 | 64.953 | 1.00 | 24.88 | B | C |
| ATOM | 2802 | CB | SER | B | 451 | 43.458 | 76.189 | 65.643 | 1.00 | 23.65 | B | C |
| ATOM | 2803 | OG | SER | B | 451 | 42.949 | 77.347 | 65.023 | 1.00 | 26.07 | B | O |
| ATOM | 2804 | C | SER | B | 451 | 41.364 | 75.028 | 64.936 | 1.00 | 23.54 | B | C |
| ATOM | 2805 | O | SER | B | 451 | 40.726 | 74.918 | 65.984 | 1.00 | 25.53 | B | O |
| ATOM | 2806 | N | ASN | B | 452 | 40.780 | 75.197 | 63.748 | 1.00 | 20.94 | B | N |
| ATOM | 2807 | CA | ASN | B | 452 | 39.326 | 75.271 | 63.617 | 1.00 | 17.97 | B | C |
| ATOM | 2808 | CB | ASN | B | 452 | 38.913 | 76.580 | 62.953 | 1.00 | 16.76 | B | C |
| ATOM | 2809 | CG | ASN | B | 452 | 38.962 | 77.750 | 63.904 | 1.00 | 17.13 | B | C |
| ATOM | 2810 | OD1 | ASN | B | 452 | 40.009 | 78.046 | 64.471 | 1.00 | 19.80 | B | O |
| ATOM | 2811 | ND2 | ASN | B | 452 | 37.830 | 78.429 | 64.084 | 1.00 | 14.42 | B | N |
| ATOM | 2812 | C | ASN | B | 452 | 38.727 | 74.108 | 62.836 | 1.00 | 17.03 | B | C |
| ATOM | 2813 | O | ASN | B | 452 | 37.627 | 74.227 | 62.301 | 1.00 | 17.16 | B | O |
| ATOM | 2814 | N | MET | B | 453 | 39.446 | 72.988 | 62.786 | 1.00 | 16.23 | B | N |
| ATOM | 2815 | CA | MET | B | 453 | 38.985 | 71.798 | 62.081 | 1.00 | 16.41 | B | C |
| ATOM | 2816 | CB | MET | B | 453 | 39.596 | 71.749 | 60.678 | 1.00 | 17.85 | B | C |
| ATOM | 2817 | CG | MET | B | 453 | 38.867 | 72.542 | 59.629 | 1.00 | 18.78 | B | C |
| ATOM | 2818 | SD | MET | B | 453 | 39.627 | 72.340 | 58.000 | 1.00 | 24.82 | B | S |
| ATOM | 2819 | CE | MET | B | 453 | 38.336 | 72.987 | 56.971 | 1.00 | 21.21 | B | C |
| ATOM | 2820 | C | MET | B | 453 | 39.362 | 70.494 | 62.793 | 1.00 | 16.46 | B | C |
| ATOM | 2821 | O | MET | B | 453 | 40.495 | 70.339 | 63.226 | 1.00 | 18.01 | B | O |
| ATOM | 2822 | N | THR | B | 454 | 38.409 | 69.569 | 62.919 | 1.00 | 15.86 | B | N |
| ATOM | 2823 | CA | THR | B | 454 | 38.679 | 68.254 | 63.505 | 1.00 | 14.88 | B | C |
| ATOM | 2824 | CB | THR | B | 454 | 37.916 | 68.000 | 64.848 | 1.00 | 14.36 | B | C |
| ATOM | 2825 | OG1 | THR | B | 454 | 36.522 | 68.287 | 64.700 | 1.00 | 16.82 | B | O |
| ATOM | 2826 | CG2 | THR | B | 454 | 38.496 | 68.878 | 65.950 | 1.00 | 12.42 | B | C |
| ATOM | 2827 | C | THR | B | 454 | 38.233 | 67.280 | 62.411 | 1.00 | 15.39 | B | C |
| ATOM | 2828 | O | THR | B | 454 | 37.375 | 67.621 | 61.596 | 1.00 | 14.76 | B | O |
| ATOM | 2829 | N | TRP | B | 455 | 38.799 | 66.078 | 62.387 | 1.00 | 15.72 | B | N |
| ATOM | 2830 | CA | TRP | B | 455 | 38.499 | 65.134 | 61.317 | 1.00 | 16.80 | B | C |
| ATOM | 2831 | CB | TRP | B | 455 | 39.801 | 64.853 | 60.547 | 1.00 | 16.27 | B | C |
| ATOM | 2832 | CG | TRP | B | 455 | 40.429 | 66.110 | 60.025 | 1.00 | 15.08 | B | C |
| ATOM | 2833 | CD2 | TRP | B | 455 | 40.228 | 66.691 | 58.731 | 1.00 | 16.36 | B | C |
| ATOM | 2834 | CE2 | TRP | B | 455 | 40.927 | 67.919 | 58.711 | 1.00 | 16.92 | B | C |
| ATOM | 2835 | CE3 | TRP | B | 455 | 39.523 | 66.295 | 57.587 | 1.00 | 16.61 | B | C |
| ATOM | 2836 | CD1 | TRP | B | 455 | 41.223 | 66.978 | 60.713 | 1.00 | 14.32 | B | C |
| ATOM | 2837 | NE1 | TRP | B | 455 | 41.525 | 68.071 | 59.935 | 1.00 | 16.15 | B | N |
| ATOM | 2838 | CZ2 | TRP | B | 455 | 40.940 | 68.757 | 57.590 | 1.00 | 17.55 | B | C |
| ATOM | 2839 | CZ3 | TRP | B | 455 | 39.538 | 67.128 | 56.471 | 1.00 | 18.30 | B | C |
| ATOM | 2840 | CH2 | TRP | B | 455 | 40.243 | 68.345 | 56.484 | 1.00 | 15.82 | B | C |
| ATOM | 2841 | C | TRP | B | 455 | 37.817 | 63.811 | 61.643 | 1.00 | 17.48 | B | C |
| ATOM | 2842 | O | TRP | B | 455 | 38.000 | 63.243 | 62.715 | 1.00 | 17.12 | B | O |
| ATOM | 2843 | N | MET | B | 456 | 37.037 | 63.328 | 60.680 | 1.00 | 16.71 | B | N |
| ATOM | 2844 | CA | MET | B | 456 | 36.328 | 62.060 | 60.793 | 1.00 | 17.12 | B | C |
| ATOM | 2845 | CB | MET | B | 456 | 34.832 | 62.285 | 60.985 | 1.00 | 17.05 | B | C |
| ATOM | 2846 | CG | MET | B | 456 | 34.467 | 63.114 | 62.192 | 1.00 | 15.52 | B | C |
| ATOM | 2847 | SD | MET | B | 456 | 32.694 | 63.310 | 62.326 | 1.00 | 17.70 | B | S |
| ATOM | 2848 | CE | MET | B | 456 | 32.114 | 61.623 | 62.044 | 1.00 | 16.18 | B | C |
| ATOM | 2849 | C | MET | B | 456 | 36.546 | 61.300 | 59.493 | 1.00 | 18.52 | B | C |
| ATOM | 2850 | O | MET | B | 456 | 37.013 | 61.872 | 58.507 | 1.00 | 18.13 | B | O |
| ATOM | 2851 | N | ILE | B | 457 | 36.209 | 60.014 | 59.493 | 1.00 | 18.95 | B | N |
| ATOM | 2852 | CA | ILE | B | 457 | 36.363 | 59.189 | 58.304 | 1.00 | 17.90 | B | C |
| ATOM | 2853 | CB | ILE | B | 457 | 37.386 | 58.039 | 58.542 | 1.00 | 18.75 | B | C |
| ATOM | 2854 | CG2 | ILE | B | 457 | 37.087 | 56.853 | 57.632 | 1.00 | 16.60 | B | C |
| ATOM | 2855 | CG1 | ILE | B | 457 | 38.795 | 58.535 | 58.230 | 1.00 | 19.66 | B | C |
| ATOM | 2856 | CD1 | ILE | B | 457 | 39.707 | 58.483 | 59.391 | 1.00 | 22.78 | B | C |
| ATOM | 2857 | C | ILE | B | 457 | 35.009 | 58.607 | 57.915 | 1.00 | 17.61 | B | C |
| ATOM | 2858 | O | ILE | B | 457 | 34.274 | 58.096 | 58.755 | 1.00 | 16.26 | B | O |
| ATOM | 2859 | N | GLN | B | 458 | 34.666 | 58.707 | 56.636 | 1.00 | 17.18 | B | N |
| ATOM | 2860 | CA | GLN | B | 458 | 33.402 | 58.168 | 56.168 | 1.00 | 15.31 | B | C |
| ATOM | 2861 | CB | GLN | B | 458 | 32.601 | 59.237 | 55.429 | 1.00 | 16.13 | B | C |
| ATOM | 2862 | CG | GLN | B | 458 | 33.281 | 59.762 | 54.184 | 1.00 | 19.80 | B | C |
| ATOM | 2863 | CD | GLN | B | 458 | 32.431 | 60.764 | 53.423 | 1.00 | 22.74 | B | C |
| ATOM | 2864 | OE1 | GLN | B | 458 | 31.511 | 61.365 | 53.972 | 1.00 | 24.14 | B | O |
| ATOM | 2865 | NE2 | GLN | B | 458 | 32.745 | 60.950 | 52.147 | 1.00 | 22.04 | B | N |
| ATOM | 2866 | C | GLN | B | 458 | 33.692 | 57.018 | 55.237 | 1.00 | 15.32 | B | C |
| ATOM | 2867 | O | GLN | B | 458 | 34.626 | 57.077 | 54.442 | 1.00 | 17.39 | B | O |
| ATOM | 2868 | N | VAL | B | 459 | 32.922 | 55.950 | 55.362 | 1.00 | 14.32 | B | N |
| ATOM | 2869 | CA | VAL | B | 459 | 33.105 | 54.833 | 54.478 | 1.00 | 16.03 | B | C |
| ATOM | 2870 | CB | VAL | B | 459 | 33.675 | 53.569 | 55.220 | 1.00 | 16.56 | B | C |
| ATOM | 2871 | CG1 | VAL | B | 459 | 34.125 | 53.942 | 56.611 | 1.00 | 19.15 | B | C |
| ATOM | 2872 | CG2 | VAL | B | 459 | 32.683 | 52.439 | 55.236 | 1.00 | 16.95 | B | C |
| ATOM | 2873 | C | VAL | B | 459 | 31.774 | 54.574 | 53.777 | 1.00 | 16.69 | B | C |
| ATOM | 2874 | O | VAL | B | 459 | 30.786 | 54.173 | 54.390 | 1.00 | 16.67 | B | O |
| ATOM | 2875 | N | PRO | B | 460 | 31.723 | 54.885 | 52.470 | 1.00 | 16.96 | B | N |
| ATOM | 2876 | CD | PRO | B | 460 | 32.834 | 55.489 | 51.704 | 1.00 | 17.59 | B | C |
| ATOM | 2877 | CA | PRO | B | 460 | 30.529 | 54.700 | 51.642 | 1.00 | 15.78 | B | C |
| ATOM | 2878 | CB | PRO | B | 460 | 30.960 | 55.227 | 50.270 | 1.00 | 16.72 | B | C |
| ATOM | 2879 | CG | PRO | B | 460 | 32.131 | 56.143 | 50.558 | 1.00 | 15.69 | B | C |
| ATOM | 2880 | C | PRO | B | 460 | 30.090 | 53.237 | 51.600 | 1.00 | 15.32 | B | C |
| ATOM | 2881 | O | PRO | B | 460 | 30.922 | 52.330 | 51.590 | 1.00 | 15.74 | B | O |
| ATOM | 2882 | N | ARG | B | 461 | 28.784 | 53.007 | 51.596 | 1.00 | 15.03 | B | N |
| ATOM | 2883 | CA | ARG | B | 461 | 28.268 | 51.648 | 51.554 | 1.00 | 17.54 | B | C |
| ATOM | 2884 | CB | ARG | B | 461 | 26.908 | 51.585 | 52.251 | 1.00 | 13.41 | B | C |
| ATOM | 2885 | CG | ARG | B | 461 | 26.887 | 52.277 | 53.606 | 1.00 | 13.36 | B | C |
| ATOM | 2886 | CD | ARG | B | 461 | 25.628 | 51.952 | 54.399 | 1.00 | 12.91 | B | C |
| ATOM | 2887 | NE | ARG | B | 461 | 24.466 | 52.732 | 53.967 | 1.00 | 14.91 | B | N |
| ATOM | 2888 | CZ | ARG | B | 461 | 24.258 | 54.014 | 54.262 | 1.00 | 13.76 | B | C |
| ATOM | 2889 | NH1 | ARG | B | 461 | 25.131 | 54.691 | 54.992 | 1.00 | 15.59 | B | N |
| ATOM | 2890 | NH2 | ARG | B | 461 | 23.172 | 54.625 | 53.817 | 1.00 | 15.24 | B | N |
| ATOM | 2891 | C | ARG | B | 461 | 28.155 | 51.185 | 50.098 | 1.00 | 18.95 | B | C |
| ATOM | 2892 | O | ARG | B | 461 | 27.055 | 50.980 | 49.577 | 1.00 | 20.79 | B | O |
| ATOM | 2893 | N | ILE | B | 462 | 29.303 | 51.020 | 49.445 | 1.00 | 19.97 | B | N |
| ATOM | 2894 | CA | ILE | B | 462 | 29.324 | 50.598 | 48.046 | 1.00 | 19.26 | B | C |
| ATOM | 2895 | CB | ILE | B | 462 | 29.947 | 51.693 | 47.139 | 1.00 | 18.45 | B | C |
| ATOM | 2896 | CG2 | ILE | B | 462 | 29.126 | 52.964 | 47.243 | 1.00 | 18.65 | B | C |
| ATOM | 2897 | CG1 | ILE | B | 462 | 31.403 | 51.953 | 47.533 | 1.00 | 17.13 | B | C |
| ATOM | 2898 | CD1 | ILE | B | 462 | 32.059 | 53.102 | 46.774 | 1.00 | 15.75 | B | C |
| ATOM | 2899 | C | ILE | B | 462 | 30.060 | 49.291 | 47.803 | 1.00 | 18.71 | B | C |
| ATOM | 2900 | O | ILE | B | 462 | 30.848 | 49.185 | 46.866 | 1.00 | 19.51 | B | O |
| ATOM | 2901 | N | TYR | B | 463 | 29.804 | 48.299 | 48.647 | 1.00 | 18.86 | B | N |
| ATOM | 2902 | CA | TYR | B | 463 | 30.438 | 47.000 | 48.489 | 1.00 | 19.41 | B | C |
| ATOM | 2903 | CB | TYR | B | 463 | 30.024 | 46.047 | 49.613 | 1.00 | 18.21 | B | C |
| ATOM | 2904 | CG | TYR | B | 463 | 30.126 | 44.588 | 49.219 | 1.00 | 17.08 | B | C |
| ATOM | 2905 | CD1 | TYR | B | 463 | 31.354 | 43.916 | 49.261 | 1.00 | 17.27 | B | C |
| ATOM | 2906 | CE1 | TYR | B | 463 | 31.464 | 42.594 | 48.845 | 1.00 | 17.20 | B | C |
| ATOM | 2907 | CD2 | TYR | B | 463 | 29.010 | 43.895 | 48.754 | 1.00 | 14.89 | B | C |
| ATOM | 2908 | CE2 | TYR | B | 463 | 29.107 | 42.573 | 48.334 | 1.00 | 16.82 | B | C |
| ATOM | 2909 | CZ | TYR | B | 463 | 30.334 | 41.930 | 48.380 | 1.00 | 17.87 | B | C |
| ATOM | 2910 | OH | TYR | B | 463 | 30.426 | 40.627 | 47.950 | 1.00 | 19.69 | B | O |
| ATOM | 2911 | C | TYR | B | 463 | 30.017 | 46.396 | 47.155 | 1.00 | 20.74 | B | C |
| ATOM | 2912 | O | TYR | B | 463 | 30.818 | 45.763 | 46.472 | 1.00 | 21.06 | B | O |
| ATOM | 2913 | N | ASP | B | 464 | 28.750 | 46.587 | 46.800 | 1.00 | 21.06 | B | N |
| ATOM | 2914 | CA | ASP | B | 464 | 28.210 | 46.051 | 45.556 | 1.00 | 23.38 | B | C |
| ATOM | 2915 | CB | ASP | B | 464 | 26.712 | 46.374 | 45.437 | 1.00 | 23.87 | B | C |
| ATOM | 2916 | CG | ASP | B | 464 | 26.403 | 47.858 | 45.631 | 1.00 | 26.93 | B | C |
| ATOM | 2917 | OD1 | ASP | B | 464 | 25.321 | 48.300 | 45.197 | 1.00 | 28.02 | B | O |
| ATOM | 2918 | OD2 | ASP | B | 464 | 27.229 | 48.589 | 46.214 | 1.00 | 28.88 | B | O |
| ATOM | 2919 | C | ASP | B | 464 | 28.960 | 46.579 | 44.337 | 1.00 | 23.82 | B | C |
| ATOM | 2920 | O | ASP | B | 464 | 29.173 | 45.856 | 43.367 | 1.00 | 23.62 | B | O |
| ATOM | 2921 | N | VAL | B | 465 | 29.366 | 47.840 | 44.392 | 1.00 | 24.45 | B | N |
| ATOM | 2922 | CA | VAL | B | 465 | 30.099 | 48.441 | 43.293 | 1.00 | 24.99 | B | C |
| ATOM | 2923 | CB | VAL | B | 465 | 30.266 | 49.965 | 43.509 | 1.00 | 24.16 | B | C |
| ATOM | 2924 | CG1 | VAL | B | 465 | 31.224 | 50.542 | 42.488 | 1.00 | 23.70 | B | C |
| ATOM | 2925 | CG2 | VAL | B | 465 | 28.917 | 50.649 | 43.398 | 1.00 | 23.26 | B | C |
| ATOM | 2926 | C | VAL | B | 465 | 31.474 | 47.779 | 43.169 | 1.00 | 26.65 | B | C |
| ATOM | 2927 | O | VAL | B | 465 | 31.872 | 47.364 | 42.080 | 1.00 | 27.99 | B | O |
| ATOM | 2928 | N | PHE | B | 466 | 32.188 | 47.673 | 44.288 | 1.00 | 26.79 | B | N |
| ATOM | 2929 | CA | PHE | B | 466 | 33.518 | 47.067 | 44.311 | 1.00 | 27.34 | B | C |
| ATOM | 2930 | CB | PHE | B | 466 | 34.163 | 47.241 | 45.690 | 1.00 | 28.37 | B | C |
| ATOM | 2931 | CG | PHE | B | 466 | 34.544 | 48.662 | 46.014 | 1.00 | 28.53 | B | C |
| ATOM | 2932 | CD1 | PHE | B | 466 | 35.101 | 49.487 | 45.046 | 1.00 | 28.81 | B | C |
| ATOM | 2933 | CD2 | PHE | B | 466 | 34.349 | 49.172 | 47.294 | 1.00 | 29.90 | B | C |
| ATOM | 2934 | CE1 | PHE | B | 466 | 35.459 | 50.799 | 45.343 | 1.00 | 29.25 | B | C |
| ATOM | 2935 | CE2 | PHE | B | 466 | 34.705 | 50.485 | 47.602 | 1.00 | 29.95 | B | C |
| ATOM | 2936 | CZ | PHE | B | 466 | 35.261 | 51.298 | 46.624 | 1.00 | 29.75 | B | C |
| ATOM | 2937 | C | PHE | B | 466 | 33.481 | 45.582 | 43.973 | 1.00 | 27.28 | B | C |
| ATOM | 2938 | O | PHE | B | 466 | 34.407 | 45.059 | 43.363 | 1.00 | 28.29 | B | O |
| ATOM | 2939 | N | ARG | B | 467 | 32.414 | 44.909 | 44.386 | 1.00 | 27.68 | B | N |
| ATOM | 2940 | CA | ARG | B | 467 | 32.244 | 43.483 | 44.138 | 1.00 | 27.60 | B | C |
| ATOM | 2941 | CB | ARG | B | 467 | 31.056 | 42.955 | 44.938 | 1.00 | 29.63 | B | C |
| ATOM | 2942 | CG | ARG | B | 467 | 30.729 | 41.498 | 44.674 | 1.00 | 30.55 | B | C |
| ATOM | 2943 | CD | ARG | B | 467 | 31.898 | 40.603 | 45.057 | 1.00 | 35.25 | B | C |
| ATOM | 2944 | NE | ARG | B | 467 | 31.588 | 39.207 | 44.788 | 1.00 | 38.76 | B | N |
| ATOM | 2945 | CZ | ARG | B | 467 | 31.523 | 38.686 | 43.569 | 1.00 | 40.24 | B | C |
| ATOM | 2946 | NH1 | ARG | B | 467 | 31.750 | 39.448 | 42.510 | 1.00 | 41.85 | B | N |
| ATOM | 2947 | NH2 | ARG | B | 467 | 31.206 | 37.410 | 43.405 | 1.00 | 43.55 | B | N |
| ATOM | 2948 | C | ARG | B | 467 | 32.028 | 43.171 | 42.661 | 1.00 | 28.80 | B | C |
| ATOM | 2949 | O | ARG | B | 467 | 32.637 | 42.248 | 42.117 | 1.00 | 28.89 | B | O |
| ATOM | 2950 | N | SER | B | 468 | 31.151 | 43.934 | 42.018 | 1.00 | 28.69 | B | N |
| ATOM | 2951 | CA | SER | B | 468 | 30.858 | 43.733 | 40.605 | 1.00 | 29.55 | B | C |
| ATOM | 2952 | CB | SER | B | 468 | 29.697 | 44.631 | 40.175 | 1.00 | 28.81 | B | C |
| ATOM | 2953 | OG | SER | B | 468 | 30.070 | 45.992 | 40.241 | 1.00 | 33.14 | B | O |
| ATOM | 2954 | C | SER | B | 468 | 32.088 | 44.006 | 39.741 | 1.00 | 28.79 | B | C |
| ATOM | 2955 | O | SER | B | 468 | 32.208 | 43.473 | 38.641 | 1.00 | 29.85 | B | O |
| ATOM | 2956 | N | LYS | B | 469 | 32.997 | 44.837 | 40.245 | 1.00 | 28.73 | B | N |
| ATOM | 2957 | CA | LYS | B | 469 | 34.240 | 45.165 | 39.545 | 1.00 | 28.26 | B | C |
| ATOM | 2958 | CB | LYS | B | 469 | 34.735 | 46.548 | 39.963 | 1.00 | 29.75 | B | C |
| ATOM | 2959 | CG | LYS | B | 469 | 34.189 | 47.705 | 39.155 | 1.00 | 33.76 | B | C |
| ATOM | 2960 | CD | LYS | B | 469 | 34.781 | 49.023 | 39.645 | 1.00 | 36.92 | B | C |
| ATOM | 2961 | CE | LYS | B | 469 | 34.318 | 50.204 | 38.801 | 1.00 | 39.66 | B | C |
| ATOM | 2962 | NZ | LYS | B | 469 | 32.831 | 50.290 | 38.722 | 1.00 | 41.85 | B | N |
| ATOM | 2963 | C | LYS | B | 469 | 35.304 | 44.134 | 39.933 | 1.00 | 28.79 | B | C |
| ATOM | 2964 | O | LYS | B | 469 | 36.444 | 44.189 | 39.473 | 1.00 | 27.52 | B | O |
| ATOM | 2965 | N | ASN | B | 470 | 34.919 | 43.209 | 40.803 | 1.00 | 29.07 | B | N |
| ATOM | 2966 | CA | ASN | B | 470 | 35.812 | 42.170 | 41.285 | 1.00 | 30.80 | B | C |
| ATOM | 2967 | CB | ASN | B | 470 | 36.221 | 41.259 | 40.137 | 1.00 | 32.33 | B | C |
| ATOM | 2968 | CG | ASN | B | 470 | 35.034 | 40.572 | 39.510 | 1.00 | 33.48 | B | C |
| ATOM | 2969 | OD1 | ASN | B | 470 | 34.429 | 39.687 | 40.113 | 1.00 | 35.11 | B | O |
| ATOM | 2970 | ND2 | ASN | B | 470 | 34.680 | 40.986 | 38.297 | 1.00 | 33.30 | B | N |
| ATOM | 2971 | C | ASN | B | 470 | 37.035 | 42.737 | 41.986 | 1.00 | 30.97 | B | C |
| ATOM | 2972 | O | ASN | B | 470 | 38.153 | 42.254 | 41.816 | 1.00 | 29.48 | B | O |
| ATOM | 2973 | N | PHE | B | 471 | 36.804 | 43.779 | 42.775 | 1.00 | 32.29 | B | N |
| ATOM | 2974 | CA | PHE | B | 471 | 37.859 | 44.410 | 43.551 | 1.00 | 32.11 | B | C |
| ATOM | 2975 | CB | PHE | B | 471 | 37.522 | 45.871 | 43.839 | 1.00 | 33.53 | B | C |
| ATOM | 2976 | CG | PHE | B | 471 | 37.923 | 46.818 | 42.749 | 1.00 | 35.42 | B | C |
| ATOM | 2977 | CD1 | PHE | B | 471 | 38.724 | 46.397 | 41.694 | 1.00 | 36.95 | B | C |
| ATOM | 2978 | CD2 | PHE | B | 471 | 37.494 | 48.140 | 42.778 | 1.00 | 37.38 | B | C |
| ATOM | 2979 | CE1 | PHE | B | 471 | 39.095 | 47.280 | 40.678 | 1.00 | 36.49 | B | C |
| ATOM | 2980 | CE2 | PHE | B | 471 | 37.858 | 49.032 | 41.770 | 1.00 | 38.62 | B | C |
| ATOM | 2981 | CZ | PHE | B | 471 | 38.661 | 48.599 | 40.718 | 1.00 | 37.95 | B | C |
| ATOM | 2982 | C | PHE | B | 471 | 37.924 | 43.650 | 44.869 | 1.00 | 31.33 | B | C |
| ATOM | 2983 | O | PHE | B | 471 | 38.951 | 43.658 | 45.546 | 1.00 | 33.10 | B | O |
| ATOM | 2984 | N | LEU | B | 472 | 36.815 | 42.997 | 45.219 | 1.00 | 28.70 | B | N |
| ATOM | 2985 | CA | LEU | B | 472 | 36.704 | 42.222 | 46.455 | 1.00 | 28.37 | B | C |
| ATOM | 2986 | CB | LEU | B | 472 | 35.973 | 43.023 | 47.546 | 1.00 | 26.91 | B | C |
| ATOM | 2987 | CG | LEU | B | 472 | 36.407 | 44.451 | 47.879 | 1.00 | 27.35 | B | C |
| ATOM | 2988 | CD1 | LEU | B | 472 | 35.257 | 45.183 | 48.545 | 1.00 | 28.12 | B | C |
| ATOM | 2989 | CD2 | LEU | B | 472 | 37.627 | 44.424 | 48.782 | 1.00 | 26.17 | B | C |
| ATOM | 2990 | C | LEU | B | 472 | 35.934 | 40.924 | 46.231 | 1.00 | 26.82 | B | C |
| ATOM | 2991 | O | LEU | B | 472 | 35.053 | 40.851 | 45.375 | 1.00 | 25.71 | B | O |
| ATOM | 2992 | N | PRO | B | 473 | 36.260 | 39.881 | 47.011 | 1.00 | 26.23 | B | N |
| ATOM | 2993 | CD | PRO | B | 473 | 37.332 | 39.867 | 48.023 | 1.00 | 26.26 | B | C |
| ATOM | 2994 | CA | PRO | B | 473 | 35.595 | 38.581 | 46.902 | 1.00 | 24.96 | B | C |
| ATOM | 2995 | CB | PRO | B | 473 | 36.679 | 37.593 | 47.324 | 1.00 | 25.24 | B | C |
| ATOM | 2996 | CG | PRO | B | 473 | 37.601 | 38.393 | 48.230 | 1.00 | 26.93 | B | C |
| ATOM | 2997 | C | PRO | B | 473 | 34.349 | 38.460 | 47.773 | 1.00 | 24.58 | B | C |
| ATOM | 2998 | O | PRO | B | 473 | 33.417 | 37.728 | 47.433 | 1.00 | 24.91 | B | O |
| ATOM | 2999 | N | HIS | B | 474 | 34.335 | 39.182 | 48.892 | 1.00 | 24.10 | B | N |
| ATOM | 3000 | CA | HIS | B | 474 | 33.213 | 39.139 | 49.841 | 1.00 | 23.91 | B | C |
| ATOM | 3001 | CB | HIS | B | 474 | 33.304 | 37.871 | 50.704 | 1.00 | 22.96 | B | C |
| ATOM | 3002 | CG | HIS | B | 474 | 34.625 | 37.713 | 51.391 | 1.00 | 22.97 | B | C |
| ATOM | 3003 | CD2 | HIS | B | 474 | 35.231 | 38.465 | 52.340 | 1.00 | 23.52 | B | C |
| ATOM | 3004 | ND1 | HIS | B | 474 | 35.520 | 36.716 | 51.067 | 1.00 | 22.32 | B | N |
| ATOM | 3005 | CE1 | HIS | B | 474 | 36.619 | 36.861 | 51.784 | 1.00 | 21.84 | B | C |
| ATOM | 3006 | NE2 | HIS | B | 474 | 36.469 | 37.915 | 52.565 | 1.00 | 25.39 | B | N |
| ATOM | 3007 | C | HIS | B | 474 | 33.223 | 40.375 | 50.752 | 1.00 | 23.12 | B | C |
| ATOM | 3008 | O | HIS | B | 474 | 34.173 | 41.161 | 50.738 | 1.00 | 22.18 | B | O |
| ATOM | 3009 | N | PHE | B | 475 | 32.175 | 40.528 | 51.557 | 1.00 | 23.30 | B | N |
| ATOM | 3010 | CA | PHE | B | 475 | 32.057 | 41.678 | 52.455 | 1.00 | 23.11 | B | C |
| ATOM | 3011 | CB | PHE | B | 475 | 30.658 | 41.730 | 53.075 | 1.00 | 20.74 | B | C |
| ATOM | 3012 | CG | PHE | B | 475 | 30.320 | 43.058 | 53.690 | 1.00 | 22.09 | B | C |
| ATOM | 3013 | CD1 | PHE | B | 475 | 30.133 | 43.177 | 55.066 | 1.00 | 20.94 | B | C |
| ATOM | 3014 | CD2 | PHE | B | 475 | 30.195 | 44.197 | 52.899 | 1.00 | 22.49 | B | C |
| ATOM | 3015 | CE1 | PHE | B | 475 | 29.828 | 44.406 | 55.643 | 1.00 | 19.81 | B | C |
| ATOM | 3016 | CE2 | PHE | B | 475 | 29.889 | 45.439 | 53.469 | 1.00 | 22.15 | B | C |
| ATOM | 3017 | CZ | PHE | B | 475 | 29.705 | 45.538 | 54.847 | 1.00 | 20.50 | B | C |
| ATOM | 3018 | C | PHE | B | 475 | 33.111 | 41.691 | 53.562 | 1.00 | 21.93 | B | C |
| ATOM | 3019 | O | PHE | B | 475 | 33.562 | 42.753 | 53.987 | 1.00 | 22.76 | B | O |
| ATOM | 3020 | N | GLY | B | 476 | 33.506 | 40.508 | 54.016 | 1.00 | 21.39 | B | N |
| ATOM | 3021 | CA | GLY | B | 476 | 34.503 | 40.416 | 55.066 | 1.00 | 19.40 | B | C |
| ATOM | 3022 | C | GLY | B | 476 | 35.803 | 41.088 | 54.691 | 1.00 | 19.66 | B | C |
| ATOM | 3023 | O | GLY | B | 476 | 36.492 | 41.650 | 55.549 | 1.00 | 17.77 | B | O |
| ATOM | 3024 | N | LYS | B | 477 | 36.137 | 41.041 | 53.402 | 1.00 | 20.49 | B | N |
| ATOM | 3025 | CA | LYS | B | 477 | 37.370 | 41.644 | 52.913 | 1.00 | 19.54 | B | C |
| ATOM | 3026 | CB | LYS | B | 477 | 37.691 | 41.127 | 51.512 | 1.00 | 20.19 | B | C |
| ATOM | 3027 | CG | LYS | B | 477 | 39.000 | 41.634 | 50.960 | 1.00 | 21.17 | B | C |
| ATOM | 3028 | CD | LYS | B | 477 | 40.189 | 41.094 | 51.736 | 1.00 | 24.54 | B | C |
| ATOM | 3029 | CE | LYS | B | 477 | 41.472 | 41.782 | 51.302 | 1.00 | 25.60 | B | C |
| ATOM | 3030 | NZ | LYS | B | 477 | 42.665 | 41.211 | 51.983 | 1.00 | 28.70 | B | N |
| ATOM | 3031 | C | LYS | B | 477 | 37.284 | 43.163 | 52.907 | 1.00 | 18.67 | B | C |
| ATOM | 3032 | O | LYS | B | 477 | 38.305 | 43.848 | 52.971 | 1.00 | 19.61 | B | O |
| ATOM | 3033 | N | MET | B | 478 | 36.067 | 43.694 | 52.825 | 1.00 | 19.33 | B | N |
| ATOM | 3034 | CA | MET | B | 478 | 35.888 | 45.142 | 52.848 | 1.00 | 20.54 | B | C |
| ATOM | 3035 | CB | MET | B | 478 | 34.479 | 45.536 | 52.389 | 1.00 | 19.93 | B | C |
| ATOM | 3036 | CG | MET | B | 478 | 34.357 | 47.015 | 52.036 | 1.00 | 19.72 | B | C |
| ATOM | 3037 | SD | MET | B | 478 | 32.667 | 47.543 | 51.664 | 1.00 | 22.18 | B | S |
| ATOM | 3038 | CE | MET | B | 478 | 32.875 | 49.305 | 51.519 | 1.00 | 16.83 | B | C |
| ATOM | 3039 | C | MET | B | 478 | 36.105 | 45.618 | 54.279 | 1.00 | 20.69 | B | C |
| ATOM | 3040 | O | MET | B | 478 | 36.807 | 46.604 | 54.521 | 1.00 | 21.04 | B | O |
| ATOM | 3041 | N | LEU | B | 479 | 35.501 | 44.897 | 55.220 | 1.00 | 18.75 | B | N |
| ATOM | 3042 | CA | LEU | B | 479 | 35.615 | 45.215 | 56.637 | 1.00 | 19.61 | B | C |
| ATOM | 3043 | CB | LEU | B | 479 | 34.786 | 44.230 | 57.466 | 1.00 | 17.44 | B | C |
| ATOM | 3044 | CG | LEU | B | 479 | 33.259 | 44.364 | 57.415 | 1.00 | 15.55 | B | C |
| ATOM | 3045 | CD1 | LEU | B | 479 | 32.623 | 43.224 | 58.198 | 1.00 | 14.97 | B | C |
| ATOM | 3046 | CD2 | LEU | B | 479 | 32.832 | 45.699 | 57.994 | 1.00 | 13.51 | B | C |
| ATOM | 3047 | C | LEU | B | 479 | 37.079 | 45.137 | 57.054 | 1.00 | 20.11 | B | C |
| ATOM | 3048 | O | LEU | B | 479 | 37.562 | 45.958 | 57.841 | 1.00 | 19.87 | B | O |
| ATOM | 3049 | N | GLU | B | 480 | 37.785 | 44.151 | 56.510 | 1.00 | 21.01 | B | N |
| ATOM | 3050 | CA | GLU | B | 480 | 39.195 | 43.968 | 56.818 | 1.00 | 22.05 | B | C |
| ATOM | 3051 | CB | GLU | B | 480 | 39.706 | 42.675 | 56.181 | 1.00 | 24.42 | B | C |
| ATOM | 3052 | CG | GLU | B | 480 | 41.211 | 42.618 | 56.025 | 1.00 | 29.69 | B | C |
| ATOM | 3053 | CD | GLU | B | 480 | 41.728 | 41.202 | 55.961 | 1.00 | 32.83 | B | C |
| ATOM | 3054 | OE1 | GLU | B | 480 | 40.909 | 40.277 | 55.794 | 1.00 | 34.39 | B | O |
| ATOM | 3055 | OE2 | GLU | B | 480 | 42.958 | 41.012 | 56.079 | 1.00 | 37.09 | B | O |
| ATOM | 3056 | C | GLU | B | 480 | 40.036 | 45.152 | 56.345 | 1.00 | 21.97 | B | C |
| ATOM | 3057 | O | GLU | B | 480 | 40.875 | 45.654 | 57.091 | 1.00 | 21.62 | B | O |
| ATOM | 3058 | N | ASN | B | 481 | 39.810 | 45.599 | 55.111 | 1.00 | 22.14 | B | N |
| ATOM | 3059 | CA | ASN | B | 481 | 40.560 | 46.728 | 54.568 | 1.00 | 20.88 | B | C |
| ATOM | 3060 | CB | ASN | B | 481 | 40.209 | 46.951 | 53.100 | 1.00 | 22.56 | B | C |
| ATOM | 3061 | CG | ASN | B | 481 | 40.656 | 45.808 | 52.218 | 1.00 | 25.25 | B | C |
| ATOM | 3062 | OD1 | ASN | B | 481 | 40.049 | 45.544 | 51.183 | 1.00 | 27.89 | B | O |
| ATOM | 3063 | ND2 | ASN | B | 481 | 41.722 | 45.121 | 52.621 | 1.00 | 25.06 | B | N |
| ATOM | 3064 | C | ASN | B | 481 | 40.264 | 47.996 | 55.349 | 1.00 | 19.71 | B | C |
| ATOM | 3065 | O | ASN | B | 481 | 41.120 | 48.870 | 55.476 | 1.00 | 18.58 | B | O |
| ATOM | 3066 | N | VAL | B | 482 | 39.046 | 48.098 | 55.869 | 1.00 | 19.48 | B | N |
| ATOM | 3067 | CA | VAL | B | 482 | 38.663 | 49.276 | 56.637 | 1.00 | 20.49 | B | C |
| ATOM | 3068 | CB | VAL | B | 482 | 37.121 | 49.408 | 56.757 | 1.00 | 19.10 | B | C |
| ATOM | 3069 | CG1 | VAL | B | 482 | 36.768 | 50.575 | 57.671 | 1.00 | 18.04 | B | C |
| ATOM | 3070 | CG2 | VAL | B | 482 | 36.506 | 49.632 | 55.382 | 1.00 | 18.90 | B | C |
| ATOM | 3071 | C | VAL | B | 482 | 39.248 | 49.284 | 58.049 | 1.00 | 20.58 | B | C |
| ATOM | 3072 | O | VAL | B | 482 | 39.832 | 50.283 | 58.479 | 1.00 | 20.46 | B | O |
| ATOM | 3073 | N | PHE | B | 483 | 39.124 | 48.169 | 58.762 | 1.00 | 20.85 | B | N |
| ATOM | 3074 | CA | PHE | B | 483 | 39.605 | 48.123 | 60.143 | 1.00 | 20.90 | B | C |
| ATOM | 3075 | CB | PHE | B | 483 | 38.534 | 47.471 | 61.025 | 1.00 | 19.00 | B | C |
| ATOM | 3076 | CG | PHE | B | 483 | 37.232 | 48.227 | 61.050 | 1.00 | 17.17 | B | C |
| ATOM | 3077 | CD1 | PHE | B | 483 | 37.142 | 49.459 | 61.676 | 1.00 | 18.55 | B | C |
| ATOM | 3078 | CD2 | PHE | B | 483 | 36.101 | 47.717 | 60.426 | 1.00 | 17.64 | B | C |
| ATOM | 3079 | CE1 | PHE | B | 483 | 35.940 | 50.179 | 61.681 | 1.00 | 16.52 | B | C |
| ATOM | 3080 | CE2 | PHE | B | 483 | 34.899 | 48.424 | 60.424 | 1.00 | 16.43 | B | C |
| ATOM | 3081 | CZ | PHE | B | 483 | 34.822 | 49.658 | 61.055 | 1.00 | 16.51 | B | C |
| ATOM | 3082 | C | PHE | B | 483 | 40.971 | 47.509 | 60.463 | 1.00 | 21.44 | B | C |
| ATOM | 3083 | O | PHE | B | 483 | 41.663 | 47.997 | 61.352 | 1.00 | 22.94 | B | O |
| ATOM | 3084 | N | MET | B | 484 | 41.376 | 46.463 | 59.756 | 1.00 | 21.30 | B | N |
| ATOM | 3085 | CA | MET | B | 484 | 42.659 | 45.827 | 60.054 | 1.00 | 23.27 | B | C |
| ATOM | 3086 | CB | MET | B | 484 | 42.936 | 44.708 | 59.045 | 1.00 | 24.57 | B | C |
| ATOM | 3087 | CG | MET | B | 484 | 44.074 | 43.764 | 59.432 | 1.00 | 26.98 | B | C |
| ATOM | 3088 | SD | MET | B | 484 | 43.821 | 42.828 | 60.966 | 1.00 | 29.42 | B | S |
| ATOM | 3089 | CE | MET | B | 484 | 42.799 | 41.497 | 60.429 | 1.00 | 26.51 | B | C |
| ATOM | 3090 | C | MET | B | 484 | 43.869 | 46.768 | 60.132 | 1.00 | 23.90 | B | C |
| ATOM | 3091 | O | MET | B | 484 | 44.661 | 46.692 | 61.070 | 1.00 | 25.43 | B | O |
| ATOM | 3092 | N | PRO | B | 485 | 44.034 | 47.666 | 59.149 | 1.00 | 24.47 | B | N |
| ATOM | 3093 | CD | PRO | B | 485 | 43.208 | 47.898 | 57.953 | 1.00 | 24.82 | B | C |
| ATOM | 3094 | CA | PRO | B | 485 | 45.183 | 48.577 | 59.199 | 1.00 | 23.77 | B | C |
| ATOM | 3095 | CB | PRO | B | 485 | 45.029 | 49.425 | 57.937 | 1.00 | 24.61 | B | C |
| ATOM | 3096 | CG | PRO | B | 485 | 44.148 | 48.614 | 57.038 | 1.00 | 23.85 | B | C |
| ATOM | 3097 | C | PRO | B | 485 | 45.227 | 49.436 | 60.457 | 1.00 | 24.30 | B | C |
| ATOM | 3098 | O | PRO | B | 485 | 46.300 | 49.712 | 60.996 | 1.00 | 25.38 | B | O |
| ATOM | 3099 | N | VAL | B | 486 | 44.055 | 49.867 | 60.912 | 1.00 | 24.20 | B | N |
| ATOM | 3100 | CA | VAL | B | 486 | 43.962 | 50.702 | 62.099 | 1.00 | 23.89 | B | C |
| ATOM | 3101 | CB | VAL | B | 486 | 42.566 | 51.322 | 62.214 | 1.00 | 24.59 | B | C |
| ATOM | 3102 | CG1 | VAL | B | 486 | 42.568 | 52.417 | 63.257 | 1.00 | 25.07 | B | C |
| ATOM | 3103 | CG2 | VAL | B | 486 | 42.148 | 51.883 | 60.871 | 1.00 | 25.11 | B | C |
| ATOM | 3104 | C | VAL | B | 486 | 44.275 | 49.894 | 63.357 | 1.00 | 24.01 | B | C |
| ATOM | 3105 | O | VAL | B | 486 | 44.865 | 50.417 | 64.302 | 1.00 | 25.18 | B | O |
| ATOM | 3106 | N | PHE | B | 487 | 43.877 | 48.627 | 63.373 | 1.00 | 23.45 | B | N |
| ATOM | 3107 | CA | PHE | B | 487 | 44.162 | 47.768 | 64.515 | 1.00 | 25.97 | B | C |
| ATOM | 3108 | CB | PHE | B | 487 | 43.445 | 46.428 | 64.376 | 1.00 | 26.51 | B | C |
| ATOM | 3109 | CG | PHE | B | 487 | 42.072 | 46.407 | 64.987 | 1.00 | 27.68 | B | C |
| ATOM | 3110 | CD1 | PHE | B | 487 | 40.949 | 46.702 | 64.215 | 1.00 | 27.36 | B | C |
| ATOM | 3111 | CD2 | PHE | B | 487 | 41.897 | 46.083 | 66.328 | 1.00 | 26.03 | B | C |
| ATOM | 3112 | CE1 | PHE | B | 487 | 39.669 | 46.675 | 64.773 | 1.00 | 25.66 | B | C |
| ATOM | 3113 | CE2 | PHE | B | 487 | 40.625 | 46.053 | 66.897 | 1.00 | 25.29 | B | C |
| ATOM | 3114 | CZ | PHE | B | 487 | 39.508 | 46.350 | 66.118 | 1.00 | 25.83 | B | C |
| ATOM | 3115 | C | PHE | B | 487 | 45.669 | 47.533 | 64.556 | 1.00 | 27.90 | B | C |
| ATOM | 3116 | O | PHE | B | 487 | 46.271 | 47.495 | 65.626 | 1.00 | 28.82 | B | O |
| ATOM | 3117 | N | GLU | B | 488 | 46.271 | 47.388 | 63.378 | 1.00 | 28.35 | B | N |
| ATOM | 3118 | CA | GLU | B | 488 | 47.708 | 47.160 | 63.263 | 1.00 | 29.93 | B | C |
| ATOM | 3119 | CB | GLU | B | 488 | 48.095 | 46.946 | 61.800 | 1.00 | 31.98 | B | C |
| ATOM | 3120 | CG | GLU | B | 488 | 48.611 | 45.555 | 61.498 | 1.00 | 36.89 | B | C |
| ATOM | 3121 | CD | GLU | B | 488 | 48.071 | 45.009 | 60.185 | 1.00 | 40.88 | B | C |
| ATOM | 3122 | OE1 | GLU | B | 488 | 47.831 | 45.818 | 59.258 | 1.00 | 41.84 | B | O |
| ATOM | 3123 | OE2 | GLU | B | 488 | 47.887 | 43.772 | 60.080 | 1.00 | 42.37 | B | O |
| ATOM | 3124 | C | GLU | B | 488 | 48.523 | 48.316 | 63.831 | 1.00 | 28.88 | B | C |
| ATOM | 3125 | O | GLU | B | 488 | 49.518 | 48.099 | 64.522 | 1.00 | 29.29 | B | O |
| ATOM | 3126 | N | ALA | B | 489 | 48.111 | 49.541 | 63.529 | 1.00 | 27.00 | B | N |
| ATOM | 3127 | CA | ALA | B | 489 | 48.821 | 50.714 | 64.028 | 1.00 | 27.62 | B | C |
| ATOM | 3128 | CB | ALA | B | 489 | 48.341 | 51.965 | 63.292 | 1.00 | 24.57 | B | C |
| ATOM | 3129 | C | ALA | B | 489 | 48.628 | 50.883 | 65.544 | 1.00 | 27.27 | B | C |
| ATOM | 3130 | O | ALA | B | 489 | 49.451 | 51.504 | 66.217 | 1.00 | 26.44 | B | O |
| ATOM | 3131 | N | THR | B | 490 | 47.535 | 50.335 | 66.070 | 1.00 | 27.41 | B | N |
| ATOM | 3132 | CA | THR | B | 490 | 47.234 | 50.423 | 67.499 | 1.00 | 28.22 | B | C |
| ATOM | 3133 | CB | THR | B | 490 | 45.776 | 49.980 | 67.790 | 1.00 | 26.62 | B | C |
| ATOM | 3134 | OG1 | THR | B | 490 | 44.868 | 50.962 | 67.277 | 1.00 | 25.82 | B | O |
| ATOM | 3135 | CG2 | THR | B | 490 | 45.546 | 49.829 | 69.286 | 1.00 | 27.17 | B | C |
| ATOM | 3136 | C | THR | B | 490 | 48.188 | 49.521 | 68.279 | 1.00 | 28.79 | B | C |
| ATOM | 3137 | O | THR | B | 490 | 48.830 | 49.943 | 69.240 | 1.00 | 28.16 | B | O |
| ATOM | 3138 | N | ILE | B | 491 | 48.277 | 48.276 | 67.831 | 1.00 | 29.82 | B | N |
| ATOM | 3139 | CA | ILE | B | 491 | 49.130 | 47.272 | 68.441 | 1.00 | 30.29 | B | C |
| ATOM | 3140 | CB | ILE | B | 491 | 48.781 | 45.882 | 67.859 | 1.00 | 29.46 | B | C |
| ATOM | 3141 | CG2 | ILE | B | 491 | 50.028 | 45.090 | 67.548 | 1.00 | 32.61 | B | C |
| ATOM | 3142 | CG1 | ILE | B | 491 | 47.908 | 45.127 | 68.850 | 1.00 | 29.85 | B | C |
| ATOM | 3143 | CD1 | ILE | B | 491 | 46.528 | 44.838 | 68.325 | 1.00 | 31.15 | B | C |
| ATOM | 3144 | C | ILE | B | 491 | 50.625 | 47.575 | 68.267 | 1.00 | 30.02 | B | C |
| ATOM | 3145 | O | ILE | B | 491 | 51.412 | 47.316 | 69.173 | 1.00 | 31.28 | B | O |
| ATOM | 3146 | N | ASN | B | 492 | 51.011 | 48.125 | 67.114 | 1.00 | 30.39 | B | N |
| ATOM | 3147 | CA | ASN | B | 492 | 52.413 | 48.454 | 66.837 | 1.00 | 28.94 | B | C |
| ATOM | 3148 | CB | ASN | B | 492 | 52.983 | 47.493 | 65.794 | 1.00 | 30.30 | B | C |
| ATOM | 3149 | CG | ASN | B | 492 | 52.811 | 46.038 | 66.188 | 1.00 | 32.56 | B | C |
| ATOM | 3150 | OD1 | ASN | B | 492 | 53.172 | 45.638 | 67.296 | 1.00 | 33.79 | B | O |
| ATOM | 3151 | ND2 | ASN | B | 492 | 52.256 | 45.237 | 65.281 | 1.00 | 30.89 | B | N |
| ATOM | 3152 | C | ASN | B | 492 | 52.581 | 49.886 | 66.336 | 1.00 | 29.24 | B | C |
| ATOM | 3153 | O | ASN | B | 492 | 52.945 | 50.110 | 65.185 | 1.00 | 28.69 | B | O |
| ATOM | 3154 | N | PRO | B | 493 | 52.345 | 50.878 | 67.208 | 1.00 | 29.79 | B | N |
| ATOM | 3155 | CD | PRO | B | 493 | 51.959 | 50.742 | 68.625 | 1.00 | 29.15 | B | C |
| ATOM | 3156 | CA | PRO | B | 493 | 52.476 | 52.283 | 66.808 | 1.00 | 30.61 | B | C |
| ATOM | 3157 | CB | PRO | B | 493 | 52.240 | 53.057 | 68.109 | 1.00 | 28.45 | B | C |
| ATOM | 3158 | CG | PRO | B | 493 | 51.493 | 52.119 | 68.985 | 1.00 | 27.45 | B | C |
| ATOM | 3159 | C | PRO | B | 493 | 53.813 | 52.648 | 66.165 | 1.00 | 31.97 | B | C |
| ATOM | 3160 | O | PRO | B | 493 | 53.872 | 53.513 | 65.288 | 1.00 | 33.39 | B | O |
| ATOM | 3161 | N | GLN | B | 494 | 54.882 | 51.993 | 66.597 | 1.00 | 32.76 | B | N |
| ATOM | 3162 | CA | GLN | B | 494 | 56.208 | 52.288 | 66.069 | 1.00 | 34.64 | B | C |
| ATOM | 3163 | CB | GLN | B | 494 | 57.270 | 51.660 | 66.968 | 1.00 | 37.59 | B | C |
| ATOM | 3164 | CG | GLN | B | 494 | 57.130 | 52.057 | 68.423 | 1.00 | 40.85 | B | C |
| ATOM | 3165 | CD | GLN | B | 494 | 57.853 | 53.344 | 68.745 | 1.00 | 41.49 | B | C |
| ATOM | 3166 | OE1 | GLN | B | 494 | 58.487 | 53.459 | 69.790 | 1.00 | 45.77 | B | O |
| ATOM | 3167 | NE2 | GLN | B | 494 | 57.766 | 54.319 | 67.850 | 1.00 | 42.67 | B | N |
| ATOM | 3168 | C | GLN | B | 494 | 56.412 | 51.828 | 64.630 | 1.00 | 33.48 | B | C |
| ATOM | 3169 | O | GLN | B | 494 | 57.133 | 52.467 | 63.861 | 1.00 | 33.18 | B | O |
| ATOM | 3170 | N | ALA | B | 495 | 55.778 | 50.716 | 64.275 | 1.00 | 32.71 | B | N |
| ATOM | 3171 | CA | ALA | B | 495 | 55.880 | 50.170 | 62.929 | 1.00 | 31.71 | B | C |
| ATOM | 3172 | CB | ALA | B | 495 | 55.341 | 48.746 | 62.906 | 1.00 | 28.86 | B | C |
| ATOM | 3173 | C | ALA | B | 495 | 55.098 | 51.049 | 61.955 | 1.00 | 31.29 | B | C |
| ATOM | 3174 | O | ALA | B | 495 | 55.400 | 51.088 | 60.760 | 1.00 | 33.44 | B | O |
| ATOM | 3175 | N | HIS | B | 496 | 54.100 | 51.761 | 62.474 | 1.00 | 30.33 | B | N |
| ATOM | 3176 | CA | HIS | B | 496 | 53.268 | 52.640 | 61.656 | 1.00 | 29.06 | B | C |
| ATOM | 3177 | CB | HIS | B | 496 | 51.884 | 52.027 | 61.488 | 1.00 | 28.42 | B | C |
| ATOM | 3178 | CG | HIS | B | 496 | 51.909 | 50.574 | 61.135 | 1.00 | 28.22 | B | C |
| ATOM | 3179 | CD2 | HIS | B | 496 | 51.673 | 49.470 | 61.882 | 1.00 | 28.87 | B | C |
| ATOM | 3180 | ND1 | HIS | B | 496 | 52.180 | 50.123 | 59.861 | 1.00 | 29.19 | B | N |
| ATOM | 3181 | CE1 | HIS | B | 496 | 52.107 | 48.803 | 59.840 | 1.00 | 29.53 | B | C |
| ATOM | 3182 | NE2 | HIS | B | 496 | 51.800 | 48.383 | 61.053 | 1.00 | 27.81 | B | N |
| ATOM | 3183 | C | HIS | B | 496 | 53.143 | 54.028 | 62.286 | 1.00 | 28.63 | B | C |
| ATOM | 3184 | O | HIS | B | 496 | 52.072 | 54.426 | 62.746 | 1.00 | 28.36 | B | O |
| ATOM | 3185 | N | PRO | B | 497 | 54.244 | 54.787 | 62.300 | 1.00 | 27.21 | B | N |
| ATOM | 3186 | CD | PRO | B | 497 | 55.549 | 54.381 | 61.753 | 1.00 | 27.09 | B | C |
| ATOM | 3187 | CA | PRO | B | 497 | 54.291 | 56.135 | 62.870 | 1.00 | 27.21 | B | C |
| ATOM | 3188 | CB | PRO | B | 497 | 55.756 | 56.535 | 62.715 | 1.00 | 27.79 | B | C |
| ATOM | 3189 | CG | PRO | B | 497 | 56.257 | 55.684 | 61.594 | 1.00 | 27.78 | B | C |
| ATOM | 3190 | C | PRO | B | 497 | 53.353 | 57.176 | 62.257 | 1.00 | 27.03 | B | C |
| ATOM | 3191 | O | PRO | B | 497 | 52.669 | 57.897 | 62.983 | 1.00 | 27.20 | B | O |
| ATOM | 3192 | N | GLU | B | 498 | 53.327 | 57.268 | 60.932 | 1.00 | 26.55 | B | N |
| ATOM | 3193 | CA | GLU | B | 498 | 52.479 | 58.253 | 60.262 | 1.00 | 26.29 | B | C |
| ATOM | 3194 | CB | GLU | B | 498 | 52.816 | 58.331 | 58.765 | 1.00 | 27.53 | B | C |
| ATOM | 3195 | CG | GLU | B | 498 | 53.302 | 59.709 | 58.336 | 1.00 | 32.03 | B | C |
| ATOM | 3196 | CD | GLU | B | 498 | 53.804 | 59.759 | 56.902 | 1.00 | 34.26 | B | C |
| ATOM | 3197 | OE1 | GLU | B | 498 | 53.514 | 58.830 | 56.119 | 1.00 | 38.31 | B | O |
| ATOM | 3198 | OE2 | GLU | B | 498 | 54.492 | 60.741 | 56.553 | 1.00 | 38.15 | B | O |
| ATOM | 3199 | C | GLU | B | 498 | 50.996 | 57.968 | 60.449 | 1.00 | 24.19 | B | C |
| ATOM | 3200 | O | GLU | B | 498 | 50.207 | 58.883 | 60.688 | 1.00 | 22.53 | B | O |
| ATOM | 3201 | N | LEU | B | 499 | 50.618 | 56.699 | 60.332 | 1.00 | 23.20 | B | N |
| ATOM | 3202 | CA | LEU | B | 499 | 49.223 | 56.316 | 60.511 | 1.00 | 22.64 | B | C |
| ATOM | 3203 | CB | LEU | B | 499 | 49.024 | 54.842 | 60.150 | 1.00 | 20.60 | B | C |
| ATOM | 3204 | CG | LEU | B | 499 | 47.610 | 54.275 | 60.301 | 1.00 | 18.95 | B | C |
| ATOM | 3205 | CD1 | LEU | B | 499 | 46.601 | 55.185 | 59.618 | 1.00 | 18.15 | B | C |
| ATOM | 3206 | CD2 | LEU | B | 499 | 47.564 | 52.872 | 59.704 | 1.00 | 18.39 | B | C |
| ATOM | 3207 | C | LEU | B | 499 | 48.831 | 56.559 | 61.970 | 1.00 | 23.62 | B | C |
| ATOM | 3208 | O | LEU | B | 499 | 47.745 | 57.059 | 62.249 | 1.00 | 23.36 | B | O |
| ATOM | 3209 | N | SER | B | 500 | 49.727 | 56.205 | 62.892 | 1.00 | 24.00 | B | N |
| ATOM | 3210 | CA | SER | B | 500 | 49.489 | 56.390 | 64.324 | 1.00 | 24.12 | B | C |
| ATOM | 3211 | CB | SER | B | 500 | 50.723 | 55.965 | 65.128 | 1.00 | 23.77 | B | C |
| ATOM | 3212 | OG | SER | B | 500 | 50.851 | 54.555 | 65.183 | 1.00 | 22.24 | B | O |
| ATOM | 3213 | C | SER | B | 500 | 49.173 | 57.857 | 64.617 | 1.00 | 24.41 | B | C |
| ATOM | 3214 | O | SER | B | 500 | 48.232 | 58.167 | 65.354 | 1.00 | 25.66 | B | O |
| ATOM | 3215 | N | VAL | B | 501 | 49.967 | 58.753 | 64.036 | 1.00 | 24.19 | B | N |
| ATOM | 3216 | CA | VAL | B | 501 | 49.780 | 60.185 | 64.218 | 1.00 | 23.23 | B | C |
| ATOM | 3217 | CB | VAL | B | 501 | 50.916 | 60.967 | 63.528 | 1.00 | 23.29 | B | C |
| ATOM | 3218 | CG1 | VAL | B | 501 | 50.524 | 62.432 | 63.337 | 1.00 | 19.98 | B | C |
| ATOM | 3219 | CG2 | VAL | B | 501 | 52.184 | 60.851 | 64.357 | 1.00 | 23.03 | B | C |
| ATOM | 3220 | C | VAL | B | 501 | 48.433 | 60.632 | 63.646 | 1.00 | 23.98 | B | C |
| ATOM | 3221 | O | VAL | B | 501 | 47.689 | 61.381 | 64.284 | 1.00 | 24.62 | B | O |
| ATOM | 3222 | N | PHE | B | 502 | 48.125 | 60.161 | 62.442 | 1.00 | 23.17 | B | N |
| ATOM | 3223 | CA | PHE | B | 502 | 46.878 | 60.505 | 61.769 | 1.00 | 20.91 | B | C |
| ATOM | 3224 | CB | PHE | B | 502 | 46.822 | 59.793 | 60.405 | 1.00 | 19.73 | B | C |
| ATOM | 3225 | CG | PHE | B | 502 | 45.558 | 60.050 | 59.617 | 1.00 | 18.89 | B | C |
| ATOM | 3226 | CD1 | PHE | B | 502 | 45.157 | 61.348 | 59.308 | 1.00 | 18.74 | B | C |
| ATOM | 3227 | CD2 | PHE | B | 502 | 44.784 | 58.987 | 59.164 | 1.00 | 18.00 | B | C |
| ATOM | 3228 | CE1 | PHE | B | 502 | 44.003 | 61.585 | 58.554 | 1.00 | 18.91 | B | C |
| ATOM | 3229 | CE2 | PHE | B | 502 | 43.632 | 59.209 | 58.410 | 1.00 | 21.21 | B | C |
| ATOM | 3230 | CZ | PHE | B | 502 | 43.238 | 60.516 | 58.103 | 1.00 | 19.33 | B | C |
| ATOM | 3231 | C | PHE | B | 502 | 45.687 | 60.096 | 62.639 | 1.00 | 20.96 | B | C |
| ATOM | 3232 | O | PHE | B | 502 | 44.762 | 60.879 | 62.858 | 1.00 | 20.26 | B | O |
| ATOM | 3233 | N | LEU | B | 503 | 45.727 | 58.868 | 63.146 | 1.00 | 21.04 | B | N |
| ATOM | 3234 | CA | LEU | B | 503 | 44.647 | 58.344 | 63.976 | 1.00 | 20.47 | B | C |
| ATOM | 3235 | CB | LEU | B | 503 | 44.959 | 56.906 | 64.379 | 1.00 | 18.13 | B | C |
| ATOM | 3236 | CG | LEU | B | 503 | 44.775 | 55.882 | 63.260 | 1.00 | 19.46 | B | C |
| ATOM | 3237 | CD1 | LEU | B | 503 | 45.201 | 54.515 | 63.758 | 1.00 | 17.74 | B | C |
| ATOM | 3238 | CD2 | LEU | B | 503 | 43.320 | 55.870 | 62.799 | 1.00 | 15.62 | B | C |
| ATOM | 3239 | C | LEU | B | 503 | 44.363 | 59.186 | 65.221 | 1.00 | 21.07 | B | C |
| ATOM | 3240 | O | LEU | B | 503 | 43.270 | 59.119 | 65.786 | 1.00 | 22.31 | B | O |
| ATOM | 3241 | N | LYS | B | 504 | 45.340 | 59.976 | 65.649 | 1.00 | 20.89 | B | N |
| ATOM | 3242 | CA | LYS | B | 504 | 45.152 | 60.836 | 66.813 | 1.00 | 22.28 | B | C |
| ATOM | 3243 | CB | LYS | B | 504 | 46.499 | 61.283 | 67.382 | 1.00 | 22.33 | B | C |
| ATOM | 3244 | CG | LYS | B | 504 | 47.216 | 60.209 | 68.176 | 1.00 | 25.30 | B | C |
| ATOM | 3245 | CD | LYS | B | 504 | 48.624 | 60.652 | 68.547 | 1.00 | 26.81 | B | C |
| ATOM | 3246 | CE | LYS | B | 504 | 48.603 | 61.848 | 69.487 | 1.00 | 28.07 | B | C |
| ATOM | 3247 | NZ | LYS | B | 504 | 49.948 | 62.485 | 69.598 | 1.00 | 30.72 | B | N |
| ATOM | 3248 | C | LYS | B | 504 | 44.346 | 62.069 | 66.417 | 1.00 | 21.84 | B | C |
| ATOM | 3249 | O | LYS | B | 504 | 43.874 | 62.806 | 67.278 | 1.00 | 22.04 | B | O |
| ATOM | 3250 | N | HIS | B | 505 | 44.201 | 62.285 | 65.109 | 1.00 | 20.63 | B | N |
| ATOM | 3251 | CA | HIS | B | 505 | 43.463 | 63.428 | 64.585 | 1.00 | 17.86 | B | C |
| ATOM | 3252 | CB | HIS | B | 505 | 44.234 | 64.062 | 63.425 | 1.00 | 19.25 | B | C |
| ATOM | 3253 | CG | HIS | B | 505 | 45.484 | 64.778 | 63.841 | 1.00 | 20.53 | B | C |
| ATOM | 3254 | CD2 | HIS | B | 505 | 46.703 | 64.310 | 64.200 | 1.00 | 21.03 | B | C |
| ATOM | 3255 | ND1 | HIS | B | 505 | 45.574 | 66.153 | 63.888 | 1.00 | 22.79 | B | N |
| ATOM | 3256 | CE1 | HIS | B | 505 | 46.796 | 66.502 | 64.254 | 1.00 | 21.63 | B | C |
| ATOM | 3257 | NE2 | HIS | B | 505 | 47.500 | 65.403 | 64.450 | 1.00 | 21.32 | B | N |
| ATOM | 3258 | C | HIS | B | 505 | 42.061 | 63.053 | 64.113 | 1.00 | 16.44 | B | C |
| ATOM | 3259 | O | HIS | B | 505 | 41.291 | 63.925 | 63.716 | 1.00 | 15.92 | B | O |
| ATOM | 3260 | N | ILE | B | 506 | 41.741 | 61.761 | 64.154 | 1.00 | 14.23 | B | N |
| ATOM | 3261 | CA | ILE | B | 506 | 40.425 | 61.270 | 63.736 | 1.00 | 15.34 | B | C |
| ATOM | 3262 | CB | ILE | B | 506 | 40.522 | 59.896 | 63.017 | 1.00 | 13.54 | B | C |
| ATOM | 3263 | CG2 | ILE | B | 506 | 39.123 | 59.352 | 62.751 | 1.00 | 11.36 | B | C |
| ATOM | 3264 | CG1 | ILE | B | 506 | 41.297 | 60.036 | 61.694 | 1.00 | 13.79 | B | C |
| ATOM | 3265 | CD1 | ILE | B | 506 | 40.908 | 61.243 | 60.848 | 1.00 | 13.48 | B | C |
| ATOM | 3266 | C | ILE | B | 506 | 39.516 | 61.114 | 64.955 | 1.00 | 17.33 | B | C |
| ATOM | 3267 | O | ILE | B | 506 | 39.838 | 60.379 | 65.894 | 1.00 | 18.00 | B | O |
| ATOM | 3268 | N | THR | B | 507 | 38.372 | 61.793 | 64.925 | 1.00 | 17.90 | B | N |
| ATOM | 3269 | CA | THR | B | 507 | 37.426 | 61.762 | 66.033 | 1.00 | 17.21 | B | C |
| ATOM | 3270 | CB | THR | B | 507 | 36.764 | 63.147 | 66.219 | 1.00 | 18.41 | B | C |
| ATOM | 3271 | OG1 | THR | B | 507 | 35.818 | 63.382 | 65.166 | 1.00 | 20.12 | B | O |
| ATOM | 3272 | CG2 | THR | B | 507 | 37.819 | 64.245 | 66.200 | 1.00 | 16.14 | B | C |
| ATOM | 3273 | C | THR | B | 507 | 36.328 | 60.700 | 65.930 | 1.00 | 16.84 | B | C |
| ATOM | 3274 | O | THR | B | 507 | 35.813 | 60.237 | 66.952 | 1.00 | 15.77 | B | O |
| ATOM | 3275 | N | GLY | B | 508 | 35.972 | 60.306 | 64.709 | 1.00 | 16.13 | B | N |
| ATOM | 3276 | CA | GLY | B | 508 | 34.931 | 59.304 | 64.547 | 1.00 | 15.62 | B | C |
| ATOM | 3277 | C | GLY | B | 508 | 34.741 | 58.779 | 63.138 | 1.00 | 15.59 | B | C |
| ATOM | 3278 | O | GLY | B | 508 | 35.447 | 59.191 | 62.213 | 1.00 | 15.18 | B | O |
| ATOM | 3279 | N | PHE | B | 509 | 33.774 | 57.874 | 62.980 | 1.00 | 16.07 | B | N |
| ATOM | 3280 | CA | PHE | B | 509 | 33.454 | 57.257 | 61.692 | 1.00 | 15.57 | B | C |
| ATOM | 3281 | CB | PHE | B | 509 | 33.603 | 55.740 | 61.778 | 1.00 | 16.29 | B | C |
| ATOM | 3282 | CG | PHE | B | 509 | 35.024 | 55.274 | 61.880 | 1.00 | 20.52 | B | C |
| ATOM | 3283 | CD1 | PHE | B | 509 | 35.717 | 54.862 | 60.745 | 1.00 | 20.01 | B | C |
| ATOM | 3284 | CD2 | PHE | B | 509 | 35.670 | 55.238 | 63.111 | 1.00 | 21.03 | B | C |
| ATOM | 3285 | CE1 | PHE | B | 509 | 37.033 | 54.424 | 60.834 | 1.00 | 22.43 | B | C |
| ATOM | 3286 | CE2 | PHE | B | 509 | 36.987 | 54.800 | 63.212 | 1.00 | 21.81 | B | C |
| ATOM | 3287 | CZ | PHE | B | 509 | 37.671 | 54.392 | 62.070 | 1.00 | 22.54 | B | C |
| ATOM | 3288 | C | PHE | B | 509 | 32.036 | 57.566 | 61.206 | 1.00 | 17.34 | B | C |
| ATOM | 3289 | O | PHE | B | 509 | 31.083 | 57.568 | 61.991 | 1.00 | 16.21 | B | O |
| ATOM | 3290 | N | ASP | B | 510 | 31.906 | 57.816 | 59.902 | 1.00 | 15.44 | B | N |
| ATOM | 3291 | CA | ASP | B | 510 | 30.617 | 58.099 | 59.286 | 1.00 | 14.86 | B | C |
| ATOM | 3292 | CB | ASP | B | 510 | 30.653 | 59.464 | 58.593 | 1.00 | 14.53 | B | C |
| ATOM | 3293 | CG | ASP | B | 510 | 29.275 | 60.095 | 58.449 | 1.00 | 13.67 | B | C |
| ATOM | 3294 | OD1 | ASP | B | 510 | 28.274 | 59.364 | 58.323 | 1.00 | 12.01 | B | O |
| ATOM | 3295 | OD2 | ASP | B | 510 | 29.191 | 61.338 | 58.457 | 1.00 | 16.39 | B | O |
| ATOM | 3296 | C | ASP | B | 510 | 30.330 | 57.000 | 58.264 | 1.00 | 16.47 | B | C |
| ATOM | 3297 | O | ASP | B | 510 | 31.236 | 56.277 | 57.848 | 1.00 | 17.19 | B | O |
| ATOM | 3298 | N | SER | B | 511 | 29.065 | 56.864 | 57.881 | 1.00 | 18.53 | B | N |
| ATOM | 3299 | CA | SER | B | 511 | 28.645 | 55.869 | 56.893 | 1.00 | 18.39 | B | C |
| ATOM | 3300 | CB | SER | B | 511 | 27.888 | 54.734 | 57.573 | 1.00 | 17.77 | B | C |
| ATOM | 3301 | OG | SER | B | 511 | 27.347 | 53.855 | 56.609 | 1.00 | 19.84 | B | O |
| ATOM | 3302 | C | SER | B | 511 | 27.731 | 56.584 | 55.902 | 1.00 | 18.77 | B | C |
| ATOM | 3303 | O | SER | B | 511 | 26.708 | 57.137 | 56.296 | 1.00 | 17.76 | B | O |
| ATOM | 3304 | N | VAL | B | 512 | 28.092 | 56.571 | 54.620 | 1.00 | 19.58 | B | N |
| ATOM | 3305 | CA | VAL | B | 512 | 27.303 | 57.275 | 53.608 | 1.00 | 18.87 | B | C |
| ATOM | 3306 | CB | VAL | B | 512 | 28.066 | 58.515 | 53.095 | 1.00 | 17.52 | B | C |
| ATOM | 3307 | CG1 | VAL | B | 512 | 28.355 | 59.461 | 54.239 | 1.00 | 19.81 | B | C |
| ATOM | 3308 | CG2 | VAL | B | 512 | 29.361 | 58.088 | 52.442 | 1.00 | 19.09 | B | C |
| ATOM | 3309 | C | VAL | B | 512 | 26.862 | 56.461 | 52.389 | 1.00 | 18.70 | B | C |
| ATOM | 3310 | O | VAL | B | 512 | 27.512 | 55.496 | 51.994 | 1.00 | 18.08 | B | O |
| ATOM | 3311 | N | ASP | B | 513 | 25.749 | 56.887 | 51.800 | 1.00 | 19.24 | B | N |
| ATOM | 3312 | CA | ASP | B | 513 | 25.160 | 56.259 | 50.617 | 1.00 | 21.60 | B | C |
| ATOM | 3313 | CB | ASP | B | 513 | 25.037 | 54.737 | 50.804 | 1.00 | 21.87 | B | C |
| ATOM | 3314 | CG | ASP | B | 513 | 24.773 | 53.994 | 49.485 | 1.00 | 23.23 | B | C |
| ATOM | 3315 | OD1 | ASP | B | 513 | 24.835 | 54.620 | 48.404 | 1.00 | 20.41 | B | O |
| ATOM | 3316 | OD2 | ASP | B | 513 | 24.500 | 52.775 | 49.531 | 1.00 | 24.11 | B | O |
| ATOM | 3317 | C | ASP | B | 513 | 23.775 | 56.856 | 50.400 | 1.00 | 21.55 | B | C |
| ATOM | 3318 | O | ASP | B | 513 | 23.314 | 57.671 | 51.197 | 1.00 | 21.74 | B | O |
| ATOM | 3319 | N | ASP | B | 514 | 23.117 | 56.466 | 49.313 | 1.00 | 23.95 | B | N |
| ATOM | 3320 | CA | ASP | B | 514 | 21.767 | 56.944 | 49.029 | 1.00 | 23.75 | B | C |
| ATOM | 3321 | CB | ASP | B | 514 | 21.397 | 56.667 | 47.574 | 1.00 | 25.43 | B | C |
| ATOM | 3322 | CG | ASP | B | 514 | 20.016 | 57.183 | 47.213 | 1.00 | 27.69 | B | C |
| ATOM | 3323 | OD1 | ASP | B | 514 | 19.270 | 57.608 | 48.121 | 1.00 | 27.98 | B | O |
| ATOM | 3324 | OD2 | ASP | B | 514 | 19.674 | 57.166 | 46.015 | 1.00 | 29.62 | B | O |
| ATOM | 3325 | C | ASP | B | 514 | 20.856 | 56.152 | 49.954 | 1.00 | 23.66 | B | C |
| ATOM | 3326 | O | ASP | B | 514 | 20.558 | 54.987 | 49.691 | 1.00 | 23.14 | B | O |
| ATOM | 3327 | N | GLU | B | 515 | 20.421 | 56.786 | 51.040 | 1.00 | 23.21 | B | N |
| ATOM | 3328 | CA | GLU | B | 515 | 19.582 | 56.120 | 52.024 | 1.00 | 22.82 | B | C |
| ATOM | 3329 | CB | GLU | B | 515 | 19.409 | 56.997 | 53.267 | 1.00 | 20.97 | B | C |
| ATOM | 3330 | CG | GLU | B | 515 | 19.711 | 56.261 | 54.558 | 1.00 | 16.24 | B | C |
| ATOM | 3331 | CD | GLU | B | 515 | 19.309 | 57.053 | 55.782 | 1.00 | 15.62 | B | C |
| ATOM | 3332 | OE1 | GLU | B | 515 | 19.538 | 58.277 | 55.800 | 1.00 | 13.04 | B | O |
| ATOM | 3333 | OE2 | GLU | B | 515 | 18.766 | 56.449 | 56.724 | 1.00 | 13.53 | B | O |
| ATOM | 3334 | C | GLU | B | 515 | 18.223 | 55.695 | 51.520 | 1.00 | 24.36 | B | C |
| ATOM | 3335 | O | GLU | B | 515 | 17.580 | 54.833 | 52.124 | 1.00 | 24.47 | B | O |
| ATOM | 3336 | N | SER | B | 516 | 17.779 | 56.294 | 50.422 | 1.00 | 26.82 | B | N |
| ATOM | 3337 | CA | SER | B | 516 | 16.478 | 55.952 | 49.853 | 1.00 | 28.63 | B | C |
| ATOM | 3338 | CB | SER | B | 516 | 15.985 | 57.069 | 48.935 | 1.00 | 28.15 | B | C |
| ATOM | 3339 | OG | SER | B | 516 | 16.686 | 57.061 | 47.704 | 1.00 | 27.60 | B | O |
| ATOM | 3340 | C | SER | B | 516 | 16.531 | 54.647 | 49.072 | 1.00 | 30.36 | B | C |
| ATOM | 3341 | O | SER | B | 516 | 15.500 | 54.101 | 48.702 | 1.00 | 29.43 | B | O |
| ATOM | 3342 | N | LYS | B | 517 | 17.738 | 54.150 | 48.822 | 1.00 | 34.67 | B | N |
| ATOM | 3343 | CA | LYS | B | 517 | 17.908 | 52.908 | 48.084 | 1.00 | 39.14 | B | C |
| ATOM | 3344 | CB | LYS | B | 517 | 19.387 | 52.532 | 48.009 | 1.00 | 38.10 | B | C |
| ATOM | 3345 | CG | LYS | B | 517 | 19.921 | 52.402 | 46.596 | 1.00 | 37.17 | B | C |
| ATOM | 3346 | CD | LYS | B | 517 | 21.318 | 52.992 | 46.460 | 1.00 | 36.45 | B | C |
| ATOM | 3347 | CE | LYS | B | 517 | 22.306 | 52.338 | 47.415 | 1.00 | 35.16 | B | C |
| ATOM | 3348 | NZ | LYS | B | 517 | 23.165 | 51.335 | 46.739 | 1.00 | 36.69 | B | N |
| ATOM | 3349 | C | LYS | B | 517 | 17.130 | 51.785 | 48.747 | 1.00 | 43.41 | B | C |
| ATOM | 3350 | O | LYS | B | 517 | 16.850 | 51.829 | 49.942 | 1.00 | 44.81 | B | O |
| ATOM | 3351 | N | HIS | B | 518 | 16.786 | 50.781 | 47.951 | 1.00 | 49.51 | B | N |
| ATOM | 3352 | CA | HIS | B | 518 | 16.035 | 49.609 | 48.402 | 1.00 | 54.56 | B | C |
| ATOM | 3353 | CB | HIS | B | 518 | 15.285 | 49.021 | 47.217 | 1.00 | 61.44 | B | C |
| ATOM | 3354 | CG | HIS | B | 518 | 16.178 | 48.732 | 46.049 | 1.00 | 67.89 | B | C |
| ATOM | 3355 | CD2 | HIS | B | 518 | 16.701 | 49.551 | 45.104 | 1.00 | 69.78 | B | C |
| ATOM | 3356 | ND1 | HIS | B | 518 | 16.708 | 47.480 | 45.808 | 1.00 | 70.52 | B | N |
| ATOM | 3357 | CE1 | HIS | B | 518 | 17.520 | 47.541 | 44.767 | 1.00 | 71.98 | B | C |
| ATOM | 3358 | NE2 | HIS | B | 518 | 17.534 | 48.786 | 44.321 | 1.00 | 72.98 | B | N |
| ATOM | 3359 | C | HIS | B | 518 | 17.016 | 48.559 | 48.913 | 1.00 | 54.79 | B | C |
| ATOM | 3360 | O | HIS | B | 518 | 18.203 | 48.602 | 48.588 | 1.00 | 55.14 | B | O |
| ATOM | 3361 | N | SER | B | 519 | 16.519 | 47.606 | 49.693 | 1.00 | 54.27 | B | N |
| ATOM | 3362 | CA | SER | B | 519 | 17.376 | 46.546 | 50.215 | 1.00 | 54.61 | B | C |
| ATOM | 3363 | CB | SER | B | 519 | 17.683 | 46.780 | 51.696 | 1.00 | 55.11 | B | C |
| ATOM | 3364 | OG | SER | B | 519 | 18.531 | 45.759 | 52.193 | 1.00 | 53.92 | B | O |
| ATOM | 3365 | C | SER | B | 519 | 16.718 | 45.181 | 50.038 | 1.00 | 54.53 | B | C |
| ATOM | 3366 | O | SER | B | 519 | 17.267 | 44.296 | 49.375 | 1.00 | 54.09 | B | O |
| ATOM | 3367 | N | GLY | B | 520 | 15.538 | 45.022 | 50.636 | 1.00 | 54.79 | B | N |
| ATOM | 3368 | CA | GLY | B | 520 | 14.815 | 43.767 | 50.543 | 1.00 | 54.44 | B | C |
| ATOM | 3369 | C | GLY | B | 520 | 15.201 | 42.770 | 51.620 | 1.00 | 53.95 | B | C |
| ATOM | 3370 | O | GLY | B | 520 | 14.363 | 42.004 | 52.089 | 1.00 | 53.75 | B | O |
| ATOM | 3371 | N | HIS | B | 521 | 16.472 | 42.783 | 52.013 | 1.00 | 53.82 | B | N |
| ATOM | 3372 | CA | HIS | B | 521 | 16.983 | 41.868 | 53.031 | 1.00 | 53.43 | B | C |
| ATOM | 3373 | CB | HIS | B | 521 | 18.110 | 41.008 | 52.444 | 1.00 | 55.38 | B | C |
| ATOM | 3374 | CG | HIS | B | 521 | 19.101 | 41.779 | 51.622 | 1.00 | 57.31 | B | C |
| ATOM | 3375 | CD2 | HIS | B | 521 | 19.958 | 42.773 | 51.956 | 1.00 | 58.35 | B | C |
| ATOM | 3376 | ND1 | HIS | B | 521 | 19.288 | 41.551 | 50.275 | 1.00 | 57.84 | B | N |
| ATOM | 3377 | CE1 | HIS | B | 521 | 20.216 | 42.372 | 49.815 | 1.00 | 59.18 | B | C |
| ATOM | 3378 | NE2 | HIS | B | 521 | 20.639 | 43.123 | 50.815 | 1.00 | 59.80 | B | N |
| ATOM | 3379 | C | HIS | B | 521 | 17.513 | 42.623 | 54.242 | 1.00 | 52.40 | B | C |
| ATOM | 3380 | O | HIS | B | 521 | 18.411 | 43.449 | 54.111 | 1.00 | 53.36 | B | O |
| ATOM | 3381 | N | MET | B | 522 | 16.967 | 42.351 | 55.422 | 1.00 | 49.93 | B | N |
| ATOM | 3382 | CA | MET | B | 522 | 17.451 | 43.038 | 56.612 | 1.00 | 48.21 | B | C |
| ATOM | 3383 | CB | MET | B | 522 | 16.303 | 43.682 | 57.390 | 1.00 | 49.26 | B | C |
| ATOM | 3384 | CG | MET | B | 522 | 16.708 | 45.006 | 58.024 | 1.00 | 50.99 | B | C |
| ATOM | 3385 | SD | MET | B | 522 | 16.095 | 45.223 | 59.693 | 1.00 | 53.56 | B | S |
| ATOM | 3386 | CE | MET | B | 522 | 14.322 | 45.311 | 59.376 | 1.00 | 53.16 | B | C |
| ATOM | 3387 | C | MET | B | 522 | 18.238 | 42.124 | 57.538 | 1.00 | 45.40 | B | C |
| ATOM | 3388 | O | MET | B | 522 | 18.061 | 40.909 | 57.529 | 1.00 | 43.89 | B | O |
| ATOM | 3389 | N | PHE | B | 523 | 19.111 | 42.730 | 58.333 | 1.00 | 42.68 | B | N |
| ATOM | 3390 | CA | PHE | B | 523 | 19.946 | 41.998 | 59.276 | 1.00 | 39.85 | B | C |
| ATOM | 3391 | CB | PHE | B | 523 | 20.663 | 42.980 | 60.205 | 1.00 | 37.34 | B | C |
| ATOM | 3392 | CG | PHE | B | 523 | 21.832 | 42.384 | 60.924 | 1.00 | 33.84 | B | C |
| ATOM | 3393 | CD1 | PHE | B | 523 | 22.787 | 41.650 | 60.233 | 1.00 | 32.10 | B | C |
| ATOM | 3394 | CD2 | PHE | B | 523 | 21.983 | 42.562 | 62.293 | 1.00 | 32.53 | B | C |
| ATOM | 3395 | CE1 | PHE | B | 523 | 23.878 | 41.100 | 60.895 | 1.00 | 31.77 | B | C |
| ATOM | 3396 | CE2 | PHE | B | 523 | 23.073 | 42.015 | 62.964 | 1.00 | 32.75 | B | C |
| ATOM | 3397 | CZ | PHE | B | 523 | 24.023 | 41.283 | 62.263 | 1.00 | 31.23 | B | C |
| ATOM | 3398 | C | PHE | B | 523 | 19.142 | 41.007 | 60.110 | 1.00 | 38.47 | B | C |
| ATOM | 3399 | O | PHE | B | 523 | 18.106 | 41.353 | 60.673 | 1.00 | 37.96 | B | O |
| ATOM | 3400 | N | SER | B | 524 | 19.629 | 39.772 | 60.187 | 1.00 | 37.92 | B | N |
| ATOM | 3401 | CA | SER | B | 524 | 18.954 | 38.739 | 60.959 | 1.00 | 38.29 | B | C |
| ATOM | 3402 | CB | SER | B | 524 | 17.729 | 38.229 | 60.201 | 1.00 | 38.05 | B | C |
| ATOM | 3403 | OG | SER | B | 524 | 17.969 | 36.946 | 59.647 | 1.00 | 39.23 | B | O |
| ATOM | 3404 | C | SER | B | 524 | 19.876 | 37.572 | 61.269 | 1.00 | 38.10 | B | C |
| ATOM | 3405 | O | SER | B | 524 | 21.031 | 37.547 | 60.853 | 1.00 | 41.09 | B | O |
| ATOM | 3406 | N | SER | B | 525 | 19.346 | 36.602 | 61.998 | 1.00 | 38.92 | B | N |
| ATOM | 3407 | CA | SER | B | 525 | 20.093 | 35.412 | 62.382 | 1.00 | 40.11 | B | C |
| ATOM | 3408 | CB | SER | B | 525 | 19.225 | 34.535 | 63.278 | 1.00 | 39.16 | B | C |
| ATOM | 3409 | OG | SER | B | 525 | 19.899 | 34.230 | 64.480 | 1.00 | 43.15 | B | O |
| ATOM | 3410 | C | SER | B | 525 | 20.544 | 34.595 | 61.176 | 1.00 | 40.83 | B | C |
| ATOM | 3411 | O | SER | B | 525 | 21.609 | 33.975 | 61.198 | 1.00 | 41.12 | B | O |
| ATOM | 3412 | N | LYS | B | 526 | 19.725 | 34.596 | 60.129 | 1.00 | 40.70 | B | N |
| ATOM | 3413 | CA | LYS | B | 526 | 20.022 | 33.842 | 58.920 | 1.00 | 41.10 | B | C |
| ATOM | 3414 | CB | LYS | B | 526 | 18.736 | 33.598 | 58.126 | 1.00 | 43.70 | B | C |
| ATOM | 3415 | CG | LYS | B | 526 | 17.515 | 33.310 | 58.978 | 1.00 | 47.06 | B | C |
| ATOM | 3416 | CD | LYS | B | 526 | 16.957 | 31.926 | 58.688 | 1.00 | 51.00 | B | C |
| ATOM | 3417 | CE | LYS | B | 526 | 15.444 | 31.880 | 58.888 | 1.00 | 53.70 | B | C |
| ATOM | 3418 | NZ | LYS | B | 526 | 14.754 | 31.065 | 57.840 | 1.00 | 54.98 | B | N |
| ATOM | 3419 | C | LYS | B | 526 | 21.047 | 34.524 | 58.023 | 1.00 | 38.59 | B | C |
| ATOM | 3420 | O | LYS | B | 526 | 21.658 | 33.879 | 57.173 | 1.00 | 39.16 | B | O |
| ATOM | 3421 | N | SER | B | 527 | 21.236 | 35.824 | 58.213 | 1.00 | 35.73 | B | N |
| ATOM | 3422 | CA | SER | B | 527 | 22.185 | 36.577 | 57.401 | 1.00 | 34.38 | B | C |
| ATOM | 3423 | CB | SER | B | 527 | 22.254 | 38.027 | 57.889 | 1.00 | 33.66 | B | C |
| ATOM | 3424 | OG | SER | B | 527 | 20.994 | 38.663 | 57.771 | 1.00 | 30.75 | B | O |
| ATOM | 3425 | C | SER | B | 527 | 23.589 | 35.971 | 57.402 | 1.00 | 33.40 | B | C |
| ATOM | 3426 | O | SER | B | 527 | 24.150 | 35.683 | 58.460 | 1.00 | 35.33 | B | O |
| ATOM | 3427 | N | PRO | B | 528 | 24.170 | 35.754 | 56.209 | 1.00 | 31.67 | B | N |
| ATOM | 3428 | CD | PRO | B | 528 | 23.587 | 35.996 | 54.879 | 1.00 | 30.39 | B | C |
| ATOM | 3429 | CA | PRO | B | 528 | 25.519 | 35.181 | 56.124 | 1.00 | 31.35 | B | C |
| ATOM | 3430 | CB | PRO | B | 528 | 25.744 | 34.984 | 54.623 | 1.00 | 30.62 | B | C |
| ATOM | 3431 | CG | PRO | B | 528 | 24.777 | 35.898 | 53.964 | 1.00 | 31.14 | B | C |
| ATOM | 3432 | C | PRO | B | 528 | 26.568 | 36.105 | 56.729 | 1.00 | 31.08 | B | C |
| ATOM | 3433 | O | PRO | B | 528 | 26.406 | 37.325 | 56.713 | 1.00 | 31.75 | B | O |
| ATOM | 3434 | N | LYS | B | 529 | 27.635 | 35.525 | 57.272 | 1.00 | 30.12 | B | N |
| ATOM | 3435 | CA | LYS | B | 529 | 28.707 | 36.320 | 57.859 | 1.00 | 29.79 | B | C |
| ATOM | 3436 | CB | LYS | B | 529 | 29.722 | 35.416 | 58.555 | 1.00 | 29.83 | B | C |
| ATOM | 3437 | CG | LYS | B | 529 | 29.102 | 34.411 | 59.505 | 1.00 | 30.88 | B | C |
| ATOM | 3438 | CD | LYS | B | 529 | 28.633 | 35.078 | 60.786 | 1.00 | 31.54 | B | C |
| ATOM | 3439 | CE | LYS | B | 529 | 27.168 | 34.780 | 61.055 | 1.00 | 32.38 | B | C |
| ATOM | 3440 | NZ | LYS | B | 529 | 26.968 | 34.055 | 62.339 | 1.00 | 31.74 | B | N |
| ATOM | 3441 | C | LYS | B | 529 | 29.372 | 37.056 | 56.705 | 1.00 | 29.65 | B | C |
| ATOM | 3442 | O | LYS | B | 529 | 29.210 | 36.668 | 55.554 | 1.00 | 30.24 | B | O |
| ATOM | 3443 | N | PRO | B | 530 | 30.120 | 38.133 | 56.996 | 1.00 | 29.06 | B | N |
| ATOM | 3444 | CD | PRO | B | 530 | 30.353 | 38.693 | 58.340 | 1.00 | 28.57 | B | C |
| ATOM | 3445 | CA | PRO | B | 530 | 30.803 | 38.915 | 55.959 | 1.00 | 28.46 | B | C |
| ATOM | 3446 | CB | PRO | B | 530 | 31.653 | 39.902 | 56.761 | 1.00 | 27.94 | B | C |
| ATOM | 3447 | CG | PRO | B | 530 | 30.918 | 40.056 | 58.042 | 1.00 | 27.90 | B | C |
| ATOM | 3448 | C | PRO | B | 530 | 31.644 | 38.099 | 54.972 | 1.00 | 29.52 | B | C |
| ATOM | 3449 | O | PRO | B | 530 | 31.604 | 38.340 | 53.761 | 1.00 | 30.36 | B | O |
| ATOM | 3450 | N | GLN | B | 531 | 32.409 | 37.143 | 55.489 | 1.00 | 29.47 | B | N |
| ATOM | 3451 | CA | GLN | B | 531 | 33.259 | 36.315 | 54.645 | 1.00 | 30.17 | B | C |
| ATOM | 3452 | CB | GLN | B | 531 | 34.225 | 35.495 | 55.505 | 1.00 | 31.52 | B | C |
| ATOM | 3453 | CG | GLN | B | 531 | 33.549 | 34.396 | 56.318 | 1.00 | 34.12 | B | C |
| ATOM | 3454 | CD | GLN | B | 531 | 33.207 | 34.823 | 57.742 | 1.00 | 35.41 | B | C |
| ATOM | 3455 | OE1 | GLN | B | 531 | 33.130 | 36.016 | 58.052 | 1.00 | 33.49 | B | O |
| ATOM | 3456 | NE2 | GLN | B | 531 | 32.998 | 33.841 | 58.617 | 1.00 | 36.67 | B | N |
| ATOM | 3457 | C | GLN | B | 531 | 32.412 | 35.388 | 53.787 | 1.00 | 29.28 | B | C |
| ATOM | 3458 | O | GLN | B | 531 | 32.855 | 34.920 | 52.744 | 1.00 | 30.98 | B | O |
| ATOM | 3459 | N | GLU | B | 532 | 31.190 | 35.126 | 54.228 | 1.00 | 28.42 | B | N |
| ATOM | 3460 | CA | GLU | B | 532 | 30.288 | 34.259 | 53.485 | 1.00 | 29.35 | B | C |
| ATOM | 3461 | CB | GLU | B | 532 | 29.420 | 33.450 | 54.445 | 1.00 | 31.46 | B | C |
| ATOM | 3462 | CG | GLU | B | 532 | 30.181 | 32.396 | 55.238 | 1.00 | 38.52 | B | C |
| ATOM | 3463 | CD | GLU | B | 532 | 29.500 | 32.057 | 56.561 | 1.00 | 44.38 | B | C |
| ATOM | 3464 | OE1 | GLU | B | 532 | 28.333 | 32.478 | 56.762 | 1.00 | 45.04 | B | O |
| ATOM | 3465 | OE2 | GLU | B | 532 | 30.131 | 31.371 | 57.400 | 1.00 | 47.11 | B | O |
| ATOM | 3466 | C | GLU | B | 532 | 29.394 | 35.065 | 52.547 | 1.00 | 28.20 | B | C |
| ATOM | 3467 | O | GLU | B | 532 | 28.626 | 34.498 | 51.776 | 1.00 | 27.92 | B | O |
| ATOM | 3468 | N | TRP | B | 533 | 29.486 | 36.390 | 52.626 | 1.00 | 27.97 | B | N |
| ATOM | 3469 | CA | TRP | B | 533 | 28.694 | 37.266 | 51.770 | 1.00 | 26.31 | B | C |
| ATOM | 3470 | CB | TRP | B | 533 | 28.423 | 38.600 | 52.470 | 1.00 | 25.94 | B | C |
| ATOM | 3471 | CG | TRP | B | 533 | 27.409 | 39.452 | 51.764 | 1.00 | 25.40 | B | C |
| ATOM | 3472 | CD2 | TRP | B | 533 | 26.053 | 39.685 | 52.166 | 1.00 | 24.79 | B | C |
| ATOM | 3473 | CE2 | TRP | B | 533 | 25.463 | 40.514 | 51.183 | 1.00 | 25.02 | B | C |
| ATOM | 3474 | CE3 | TRP | B | 533 | 25.278 | 39.273 | 53.261 | 1.00 | 25.86 | B | C |
| ATOM | 3475 | CD1 | TRP | B | 533 | 27.581 | 40.135 | 50.587 | 1.00 | 23.90 | B | C |
| ATOM | 3476 | NE1 | TRP | B | 533 | 26.418 | 40.771 | 50.235 | 1.00 | 22.57 | B | N |
| ATOM | 3477 | CZ2 | TRP | B | 533 | 24.128 | 40.941 | 51.263 | 1.00 | 24.60 | B | C |
| ATOM | 3478 | CZ3 | TRP | B | 533 | 23.947 | 39.697 | 53.341 | 1.00 | 24.50 | B | C |
| ATOM | 3479 | CH2 | TRP | B | 533 | 23.389 | 40.523 | 52.345 | 1.00 | 25.40 | B | C |
| ATOM | 3480 | C | TRP | B | 533 | 29.503 | 37.499 | 50.502 | 1.00 | 26.45 | B | C |
| ATOM | 3481 | O | TRP | B | 533 | 30.255 | 38.469 | 50.401 | 1.00 | 25.64 | B | O |
| ATOM | 3482 | N | THR | B | 534 | 29.352 | 36.590 | 49.544 | 1.00 | 26.99 | B | N |
| ATOM | 3483 | CA | THR | B | 534 | 30.082 | 36.665 | 48.284 | 1.00 | 28.40 | B | C |
| ATOM | 3484 | CB | THR | B | 534 | 30.686 | 35.301 | 47.936 | 1.00 | 26.72 | B | C |
| ATOM | 3485 | OG1 | THR | B | 534 | 29.637 | 34.333 | 47.882 | 1.00 | 28.29 | B | O |
| ATOM | 3486 | CG2 | THR | B | 534 | 31.690 | 34.871 | 48.988 | 1.00 | 25.80 | B | C |
| ATOM | 3487 | C | THR | B | 534 | 29.221 | 37.131 | 47.104 | 1.00 | 28.86 | B | C |
| ATOM | 3488 | O | THR | B | 534 | 29.749 | 37.431 | 46.034 | 1.00 | 26.28 | B | O |
| ATOM | 3489 | N | LEU | B | 535 | 27.905 | 37.185 | 47.298 | 1.00 | 30.00 | B | N |
| ATOM | 3490 | CA | LEU | B | 535 | 27.001 | 37.622 | 46.241 | 1.00 | 31.92 | B | C |
| ATOM | 3491 | CB | LEU | B | 535 | 25.545 | 37.392 | 46.647 | 1.00 | 31.78 | B | C |
| ATOM | 3492 | CG | LEU | B | 535 | 25.072 | 37.995 | 47.968 | 1.00 | 34.47 | B | C |
| ATOM | 3493 | CD1 | LEU | B | 535 | 23.605 | 38.352 | 47.857 | 1.00 | 33.88 | B | C |
| ATOM | 3494 | CD2 | LEU | B | 535 | 25.282 | 36.997 | 49.103 | 1.00 | 39.04 | B | C |
| ATOM | 3495 | C | LEU | B | 535 | 27.241 | 39.096 | 45.923 | 1.00 | 32.72 | B | C |
| ATOM | 3496 | O | LEU | B | 535 | 27.970 | 39.787 | 46.637 | 1.00 | 33.26 | B | O |
| ATOM | 3497 | N | GLU | B | 536 | 26.630 | 39.576 | 44.847 | 1.00 | 34.47 | B | N |
| ATOM | 3498 | CA | GLU | B | 536 | 26.820 | 40.957 | 44.430 | 1.00 | 35.92 | B | C |
| ATOM | 3499 | CB | GLU | B | 536 | 26.596 | 41.074 | 42.927 | 1.00 | 38.80 | B | C |
| ATOM | 3500 | CG | GLU | B | 536 | 27.666 | 41.877 | 42.222 | 1.00 | 45.46 | B | C |
| ATOM | 3501 | CD | GLU | B | 536 | 27.514 | 41.841 | 40.716 | 1.00 | 47.70 | B | C |
| ATOM | 3502 | OE1 | GLU | B | 536 | 27.057 | 42.858 | 40.143 | 1.00 | 49.22 | B | O |
| ATOM | 3503 | OE2 | GLU | B | 536 | 27.850 | 40.797 | 40.113 | 1.00 | 47.22 | B | O |
| ATOM | 3504 | C | GLU | B | 536 | 25.940 | 41.967 | 45.149 | 1.00 | 34.51 | B | C |
| ATOM | 3505 | O | GLU | B | 536 | 26.236 | 43.161 | 45.142 | 1.00 | 33.84 | B | O |
| ATOM | 3506 | N | LYS | B | 537 | 24.859 | 41.488 | 45.757 | 1.00 | 33.07 | B | N |
| ATOM | 3507 | CA | LYS | B | 537 | 23.937 | 42.356 | 46.482 | 1.00 | 32.25 | B | C |
| ATOM | 3508 | CB | LYS | B | 537 | 22.816 | 41.533 | 47.120 | 1.00 | 35.23 | B | C |
| ATOM | 3509 | CG | LYS | B | 537 | 21.534 | 41.500 | 46.321 | 1.00 | 40.77 | B | C |
| ATOM | 3510 | CD | LYS | B | 537 | 20.756 | 42.804 | 46.458 | 1.00 | 47.00 | B | C |
| ATOM | 3511 | CE | LYS | B | 537 | 19.450 | 42.748 | 45.664 | 1.00 | 51.22 | B | C |
| ATOM | 3512 | NZ | LYS | B | 537 | 19.013 | 44.087 | 45.158 | 1.00 | 54.35 | B | N |
| ATOM | 3513 | C | LYS | B | 537 | 24.658 | 43.124 | 47.579 | 1.00 | 29.44 | B | C |
| ATOM | 3514 | O | LYS | B | 537 | 25.552 | 42.596 | 48.236 | 1.00 | 29.94 | B | O |
| ATOM | 3515 | N | ASN | B | 538 | 24.268 | 44.376 | 47.769 | 1.00 | 27.31 | B | N |
| ATOM | 3516 | CA | ASN | B | 538 | 24.862 | 45.206 | 48.810 | 1.00 | 24.19 | B | C |
| ATOM | 3517 | CB | ASN | B | 538 | 24.665 | 46.690 | 48.479 | 1.00 | 22.79 | B | C |
| ATOM | 3518 | CG | ASN | B | 538 | 25.638 | 47.594 | 49.209 | 1.00 | 21.24 | B | C |
| ATOM | 3519 | OD1 | ASN | B | 538 | 26.777 | 47.215 | 49.481 | 1.00 | 21.03 | B | O |
| ATOM | 3520 | ND2 | ASN | B | 538 | 25.192 | 48.806 | 49.522 | 1.00 | 21.29 | B | N |
| ATOM | 3521 | C | ASN | B | 538 | 24.126 | 44.871 | 50.105 | 1.00 | 21.89 | B | C |
| ATOM | 3522 | O | ASN | B | 538 | 22.902 | 44.753 | 50.109 | 1.00 | 19.86 | B | O |
| ATOM | 3523 | N | PRO | B | 539 | 24.864 | 44.666 | 51.208 | 1.00 | 20.45 | B | N |
| ATOM | 3524 | CD | PRO | B | 539 | 26.330 | 44.671 | 51.365 | 1.00 | 20.82 | B | C |
| ATOM | 3525 | CA | PRO | B | 539 | 24.180 | 44.356 | 52.466 | 1.00 | 20.34 | B | C |
| ATOM | 3526 | CB | PRO | B | 539 | 25.326 | 44.119 | 53.454 | 1.00 | 18.97 | B | C |
| ATOM | 3527 | CG | PRO | B | 539 | 26.534 | 43.851 | 52.596 | 1.00 | 18.88 | B | C |
| ATOM | 3528 | C | PRO | B | 539 | 23.281 | 45.534 | 52.884 | 1.00 | 20.23 | B | C |
| ATOM | 3529 | O | PRO | B | 539 | 23.475 | 46.657 | 52.426 | 1.00 | 18.89 | B | O |
| ATOM | 3530 | N | SER | B | 540 | 22.300 | 45.270 | 53.745 | 1.00 | 20.00 | B | N |
| ATOM | 3531 | CA | SER | B | 540 | 21.387 | 46.308 | 54.220 | 1.00 | 19.19 | B | C |
| ATOM | 3532 | CB | SER | B | 540 | 20.212 | 45.671 | 54.967 | 1.00 | 19.06 | B | C |
| ATOM | 3533 | OG | SER | B | 540 | 20.603 | 45.203 | 56.242 | 1.00 | 19.80 | B | O |
| ATOM | 3534 | C | SER | B | 540 | 22.075 | 47.331 | 55.130 | 1.00 | 18.95 | B | C |
| ATOM | 3535 | O | SER | B | 540 | 23.190 | 47.116 | 55.598 | 1.00 | 19.02 | B | O |
| ATOM | 3536 | N | TYR | B | 541 | 21.397 | 48.450 | 55.365 | 1.00 | 18.64 | B | N |
| ATOM | 3537 | CA | TYR | B | 541 | 21.917 | 49.520 | 56.208 | 1.00 | 18.32 | B | C |
| ATOM | 3538 | CB | TYR | B | 541 | 20.856 | 50.624 | 56.343 | 1.00 | 17.41 | B | C |
| ATOM | 3539 | CG | TYR | B | 541 | 21.266 | 51.818 | 57.190 | 1.00 | 17.53 | B | C |
| ATOM | 3540 | CD1 | TYR | B | 541 | 21.147 | 51.786 | 58.582 | 1.00 | 16.93 | B | C |
| ATOM | 3541 | CE1 | TYR | B | 541 | 21.508 | 52.886 | 59.361 | 1.00 | 17.82 | B | C |
| ATOM | 3542 | CD2 | TYR | B | 541 | 21.758 | 52.983 | 56.599 | 1.00 | 16.75 | B | C |
| ATOM | 3543 | CE2 | TYR | B | 541 | 22.121 | 54.089 | 57.366 | 1.00 | 16.13 | B | C |
| ATOM | 3544 | CZ | TYR | B | 541 | 21.994 | 54.034 | 58.747 | 1.00 | 18.72 | B | C |
| ATOM | 3545 | OH | TYR | B | 541 | 22.345 | 55.119 | 59.512 | 1.00 | 14.67 | B | O |
| ATOM | 3546 | C | TYR | B | 541 | 22.304 | 48.991 | 57.589 | 1.00 | 18.76 | B | C |
| ATOM | 3547 | O | TYR | B | 541 | 23.376 | 49.305 | 58.112 | 1.00 | 18.61 | B | O |
| ATOM | 3548 | N | THR | B | 542 | 21.423 | 48.184 | 58.172 | 1.00 | 18.96 | B | N |
| ATOM | 3549 | CA | THR | B | 542 | 21.654 | 47.616 | 59.495 | 1.00 | 19.77 | B | C |
| ATOM | 3550 | CB | THR | B | 542 | 20.378 | 46.912 | 60.002 | 1.00 | 20.28 | B | C |
| ATOM | 3551 | OG1 | THR | B | 542 | 19.319 | 47.876 | 60.077 | 1.00 | 19.56 | B | O |
| ATOM | 3552 | CG2 | THR | B | 542 | 20.598 | 46.304 | 61.383 | 1.00 | 19.50 | B | C |
| ATOM | 3553 | C | THR | B | 542 | 22.847 | 46.657 | 59.519 | 1.00 | 19.30 | B | C |
| ATOM | 3554 | O | THR | B | 542 | 23.603 | 46.617 | 60.496 | 1.00 | 19.03 | B | O |
| ATOM | 3555 | N | TYR | B | 543 | 23.020 | 45.896 | 58.442 | 1.00 | 17.76 | B | N |
| ATOM | 3556 | CA | TYR | B | 543 | 24.144 | 44.967 | 58.325 | 1.00 | 17.05 | B | C |
| ATOM | 3557 | CB | TYR | B | 543 | 24.064 | 44.235 | 56.982 | 1.00 | 17.37 | B | C |
| ATOM | 3558 | CG | TYR | B | 543 | 25.002 | 43.063 | 56.829 | 1.00 | 15.50 | B | C |
| ATOM | 3559 | CD1 | TYR | B | 543 | 26.345 | 43.254 | 56.499 | 1.00 | 14.90 | B | C |
| ATOM | 3560 | CE1 | TYR | B | 543 | 27.207 | 42.168 | 56.329 | 1.00 | 15.31 | B | C |
| ATOM | 3561 | CD2 | TYR | B | 543 | 24.542 | 41.759 | 56.988 | 1.00 | 15.81 | B | C |
| ATOM | 3562 | CE2 | TYR | B | 543 | 25.393 | 40.669 | 56.822 | 1.00 | 17.68 | B | C |
| ATOM | 3563 | CZ | TYR | B | 543 | 26.723 | 40.882 | 56.492 | 1.00 | 17.39 | B | C |
| ATOM | 3564 | OH | TYR | B | 543 | 27.556 | 39.802 | 56.324 | 1.00 | 18.54 | B | O |
| ATOM | 3565 | C | TYR | B | 543 | 25.437 | 45.783 | 58.404 | 1.00 | 17.72 | B | C |
| ATOM | 3566 | O | TYR | B | 543 | 26.351 | 45.481 | 59.183 | 1.00 | 17.93 | B | O |
| ATOM | 3567 | N | TYR | B | 544 | 25.503 | 46.831 | 57.590 | 1.00 | 17.66 | B | N |
| ATOM | 3568 | CA | TYR | B | 544 | 26.666 | 47.711 | 57.574 | 1.00 | 18.80 | B | C |
| ATOM | 3569 | CB | TYR | B | 544 | 26.443 | 48.863 | 56.578 | 1.00 | 17.87 | B | C |
| ATOM | 3570 | CG | TYR | B | 544 | 26.965 | 48.629 | 55.175 | 1.00 | 18.91 | B | C |
| ATOM | 3571 | CD1 | TYR | B | 544 | 26.154 | 48.061 | 54.191 | 1.00 | 18.39 | B | C |
| ATOM | 3572 | CE1 | TYR | B | 544 | 26.621 | 47.887 | 52.882 | 1.00 | 19.12 | B | C |
| ATOM | 3573 | CD2 | TYR | B | 544 | 28.260 | 49.015 | 54.818 | 1.00 | 18.47 | B | C |
| ATOM | 3574 | CE2 | TYR | B | 544 | 28.734 | 48.846 | 53.519 | 1.00 | 19.08 | B | C |
| ATOM | 3575 | CZ | TYR | B | 544 | 27.910 | 48.286 | 52.557 | 1.00 | 19.54 | B | C |
| ATOM | 3576 | OH | TYR | B | 544 | 28.369 | 48.149 | 51.267 | 1.00 | 19.95 | B | O |
| ATOM | 3577 | C | TYR | B | 544 | 26.873 | 48.294 | 58.986 | 1.00 | 19.63 | B | C |
| ATOM | 3578 | O | TYR | B | 544 | 27.976 | 48.248 | 59.539 | 1.00 | 19.04 | B | O |
| ATOM | 3579 | N | ALA | B | 545 | 25.795 | 48.836 | 59.556 | 1.00 | 19.50 | B | N |
| ATOM | 3580 | CA | ALA | B | 545 | 25.827 | 49.450 | 60.878 | 1.00 | 19.09 | B | C |
| ATOM | 3581 | CB | ALA | B | 545 | 24.438 | 49.958 | 61.242 | 1.00 | 18.51 | B | C |
| ATOM | 3582 | C | ALA | B | 545 | 26.345 | 48.522 | 61.975 | 1.00 | 19.89 | B | C |
| ATOM | 3583 | O | ALA | B | 545 | 27.223 | 48.902 | 62.754 | 1.00 | 21.10 | B | O |
| ATOM | 3584 | N | TYR | B | 546 | 25.815 | 47.307 | 62.039 | 1.00 | 20.60 | B | N |
| ATOM | 3585 | CA | TYR | B | 546 | 26.254 | 46.374 | 63.065 | 1.00 | 20.91 | B | C |
| ATOM | 3586 | CB | TYR | B | 546 | 25.514 | 45.038 | 62.945 | 1.00 | 22.25 | B | C |
| ATOM | 3587 | CG | TYR | B | 546 | 26.046 | 44.000 | 63.913 | 1.00 | 25.12 | B | C |
| ATOM | 3588 | CD1 | TYR | B | 546 | 25.625 | 43.981 | 65.245 | 1.00 | 25.95 | B | C |
| ATOM | 3589 | CE1 | TYR | B | 546 | 26.185 | 43.101 | 66.166 | 1.00 | 24.90 | B | C |
| ATOM | 3590 | CD2 | TYR | B | 546 | 27.036 | 43.099 | 63.524 | 1.00 | 25.41 | B | C |
| ATOM | 3591 | CE2 | TYR | B | 546 | 27.602 | 42.215 | 64.437 | 1.00 | 26.31 | B | C |
| ATOM | 3592 | CZ | TYR | B | 546 | 27.175 | 42.226 | 65.756 | 1.00 | 27.40 | B | C |
| ATOM | 3593 | OH | TYR | B | 546 | 27.763 | 41.380 | 66.668 | 1.00 | 28.61 | B | O |
| ATOM | 3594 | C | TYR | B | 546 | 27.756 | 46.110 | 63.033 | 1.00 | 20.26 | B | C |
| ATOM | 3595 | O | TYR | B | 546 | 28.443 | 46.217 | 64.056 | 1.00 | 20.21 | B | O |
| ATOM | 3596 | N | TYR | B | 547 | 28.268 | 45.775 | 61.854 | 1.00 | 18.88 | B | N |
| ATOM | 3597 | CA | TYR | B | 547 | 29.679 | 45.461 | 61.713 | 1.00 | 17.66 | B | C |
| ATOM | 3598 | CB | TYR | B | 547 | 29.905 | 44.746 | 60.381 | 1.00 | 16.80 | B | C |
| ATOM | 3599 | CG | TYR | B | 547 | 29.428 | 43.309 | 60.459 | 1.00 | 16.37 | B | C |
| ATOM | 3600 | CD1 | TYR | B | 547 | 30.133 | 42.368 | 61.209 | 1.00 | 15.74 | B | C |
| ATOM | 3601 | CE1 | TYR | B | 547 | 29.659 | 41.072 | 61.369 | 1.00 | 14.75 | B | C |
| ATOM | 3602 | CD2 | TYR | B | 547 | 28.231 | 42.909 | 59.861 | 1.00 | 14.78 | B | C |
| ATOM | 3603 | CE2 | TYR | B | 547 | 27.748 | 41.605 | 60.017 | 1.00 | 13.87 | B | C |
| ATOM | 3604 | CZ | TYR | B | 547 | 28.471 | 40.696 | 60.777 | 1.00 | 14.55 | B | C |
| ATOM | 3605 | OH | TYR | B | 547 | 28.019 | 39.407 | 60.958 | 1.00 | 15.38 | B | O |
| ATOM | 3606 | C | TYR | B | 547 | 30.619 | 46.641 | 61.898 | 1.00 | 18.72 | B | C |
| ATOM | 3607 | O | TYR | B | 547 | 31.795 | 46.466 | 62.244 | 1.00 | 17.88 | B | O |
| ATOM | 3608 | N | MET | B | 548 | 30.108 | 47.846 | 61.686 | 1.00 | 18.27 | B | N |
| ATOM | 3609 | CA | MET | B | 548 | 30.929 | 49.021 | 61.896 | 1.00 | 20.09 | B | C |
| ATOM | 3610 | CB | MET | B | 548 | 30.337 | 50.215 | 61.157 | 1.00 | 21.96 | B | C |
| ATOM | 3611 | CG | MET | B | 548 | 30.870 | 50.356 | 59.745 | 1.00 | 22.00 | B | C |
| ATOM | 3612 | SD | MET | B | 548 | 30.663 | 52.019 | 59.130 | 1.00 | 31.62 | B | S |
| ATOM | 3613 | CE | MET | B | 548 | 32.191 | 52.817 | 59.730 | 1.00 | 25.34 | B | C |
| ATOM | 3614 | C | MET | B | 548 | 30.947 | 49.269 | 63.408 | 1.00 | 21.29 | B | C |
| ATOM | 3615 | O | MET | B | 548 | 31.965 | 49.662 | 63.981 | 1.00 | 20.84 | B | O |
| ATOM | 3616 | N | TYR | B | 549 | 29.812 | 49.013 | 64.053 | 1.00 | 21.06 | B | N |
| ATOM | 3617 | CA | TYR | B | 549 | 29.705 | 49.194 | 65.494 | 1.00 | 21.79 | B | C |
| ATOM | 3618 | CB | TYR | B | 549 | 28.250 | 49.018 | 65.945 | 1.00 | 21.03 | B | C |
| ATOM | 3619 | CG | TYR | B | 549 | 28.087 | 48.871 | 67.445 | 1.00 | 23.02 | B | C |
| ATOM | 3620 | CD1 | TYR | B | 549 | 28.092 | 49.990 | 68.275 | 1.00 | 22.42 | B | C |
| ATOM | 3621 | CE1 | TYR | B | 549 | 27.981 | 49.866 | 69.656 | 1.00 | 23.39 | B | C |
| ATOM | 3622 | CD2 | TYR | B | 549 | 27.962 | 47.611 | 68.039 | 1.00 | 22.07 | B | C |
| ATOM | 3623 | CE2 | TYR | B | 549 | 27.851 | 47.475 | 69.422 | 1.00 | 22.10 | B | C |
| ATOM | 3624 | CZ | TYR | B | 549 | 27.862 | 48.611 | 70.225 | 1.00 | 23.46 | B | C |
| ATOM | 3625 | OH | TYR | B | 549 | 27.766 | 48.500 | 71.594 | 1.00 | 20.03 | B | O |
| ATOM | 3626 | C | TYR | B | 549 | 30.592 | 48.171 | 66.205 | 1.00 | 21.49 | B | C |
| ATOM | 3627 | O | TYR | B | 549 | 31.360 | 48.517 | 67.102 | 1.00 | 22.09 | B | O |
| ATOM | 3628 | N | ALA | B | 550 | 30.476 | 46.913 | 65.785 | 1.00 | 21.79 | B | N |
| ATOM | 3629 | CA | ALA | B | 550 | 31.236 | 45.808 | 66.364 | 1.00 | 21.79 | B | C |
| ATOM | 3630 | CB | ALA | B | 550 | 30.871 | 44.506 | 65.652 | 1.00 | 20.27 | B | C |
| ATOM | 3631 | C | ALA | B | 550 | 32.750 | 46.018 | 66.334 | 1.00 | 22.03 | B | C |
| ATOM | 3632 | O | ALA | B | 550 | 33.432 | 45.793 | 67.332 | 1.00 | 20.53 | B | O |
| ATOM | 3633 | N | ASN | B | 551 | 33.278 | 46.447 | 65.191 | 1.00 | 22.53 | B | N |
| ATOM | 3634 | CA | ASN | B | 551 | 34.715 | 46.673 | 65.060 | 1.00 | 22.48 | B | C |
| ATOM | 3635 | CB | ASN | B | 551 | 35.096 | 46.781 | 63.578 | 1.00 | 22.24 | B | C |
| ATOM | 3636 | CG | ASN | B | 551 | 35.237 | 45.424 | 62.916 | 1.00 | 19.76 | B | C |
| ATOM | 3637 | OD1 | ASN | B | 551 | 34.322 | 44.946 | 62.247 | 1.00 | 20.41 | B | O |
| ATOM | 3638 | ND2 | ASN | B | 551 | 36.385 | 44.793 | 63.108 | 1.00 | 18.36 | B | N |
| ATOM | 3639 | C | ASN | B | 551 | 35.190 | 47.918 | 65.811 | 1.00 | 22.29 | B | C |
| ATOM | 3640 | O | ASN | B | 551 | 36.295 | 47.944 | 66.346 | 1.00 | 23.82 | B | O |
| ATOM | 3641 | N | ILE | B | 552 | 34.359 | 48.953 | 65.847 | 1.00 | 21.95 | B | N |
| ATOM | 3642 | CA | ILE | B | 552 | 34.720 | 50.180 | 66.547 | 1.00 | 20.52 | B | C |
| ATOM | 3643 | CB | ILE | B | 552 | 33.727 | 51.330 | 66.203 | 1.00 | 17.70 | B | C |
| ATOM | 3644 | CG2 | ILE | B | 552 | 33.883 | 52.492 | 67.193 | 1.00 | 14.96 | B | C |
| ATOM | 3645 | CG1 | ILE | B | 552 | 34.003 | 51.830 | 64.772 | 1.00 | 17.58 | B | C |
| ATOM | 3646 | CD1 | ILE | B | 552 | 32.956 | 52.772 | 64.219 | 1.00 | 13.36 | B | C |
| ATOM | 3647 | C | ILE | B | 552 | 34.742 | 49.923 | 68.057 | 1.00 | 20.67 | B | C |
| ATOM | 3648 | O | ILE | B | 552 | 35.584 | 50.456 | 68.782 | 1.00 | 20.06 | B | O |
| ATOM | 3649 | N | MET | B | 553 | 33.823 | 49.088 | 68.523 | 1.00 | 20.97 | B | N |
| ATOM | 3650 | CA | MET | B | 553 | 33.747 | 48.757 | 69.941 | 1.00 | 23.21 | B | C |
| ATOM | 3651 | CB | MET | B | 553 | 32.528 | 47.876 | 70.203 | 1.00 | 23.99 | B | C |
| ATOM | 3652 | CG | MET | B | 553 | 32.514 | 47.258 | 71.576 | 1.00 | 26.83 | B | C |
| ATOM | 3653 | SD | MET | B | 553 | 31.275 | 45.981 | 71.689 | 1.00 | 30.09 | B | S |
| ATOM | 3654 | CE | MET | B | 553 | 32.252 | 44.656 | 72.315 | 1.00 | 32.55 | B | C |
| ATOM | 3655 | C | MET | B | 553 | 35.019 | 48.041 | 70.404 | 1.00 | 22.71 | B | C |
| ATOM | 3656 | O | MET | B | 553 | 35.639 | 48.430 | 71.399 | 1.00 | 23.16 | B | O |
| ATOM | 3657 | N | VAL | B | 554 | 35.406 | 46.995 | 69.676 | 1.00 | 21.89 | B | N |
| ATOM | 3658 | CA | VAL | B | 554 | 36.604 | 46.240 | 70.013 | 1.00 | 20.77 | B | C |
| ATOM | 3659 | CB | VAL | B | 554 | 36.774 | 45.009 | 69.089 | 1.00 | 20.68 | B | C |
| ATOM | 3660 | CG1 | VAL | B | 554 | 38.061 | 44.261 | 69.441 | 1.00 | 22.03 | B | C |
| ATOM | 3661 | CG2 | VAL | B | 554 | 35.582 | 44.082 | 69.226 | 1.00 | 18.30 | B | C |
| ATOM | 3662 | C | VAL | B | 554 | 37.832 | 47.145 | 69.891 | 1.00 | 20.70 | B | C |
| ATOM | 3663 | O | VAL | B | 554 | 38.727 | 47.107 | 70.728 | 1.00 | 22.90 | B | O |
| ATOM | 3664 | N | LEU | B | 555 | 37.862 | 47.973 | 68.855 | 1.00 | 19.28 | B | N |
| ATOM | 3665 | CA | LEU | B | 555 | 38.981 | 48.880 | 68.636 | 1.00 | 19.46 | B | C |
| ATOM | 3666 | CB | LEU | B | 555 | 38.799 | 49.620 | 67.303 | 1.00 | 18.85 | B | C |
| ATOM | 3667 | CG | LEU | B | 555 | 39.815 | 50.708 | 66.938 | 1.00 | 19.57 | B | C |
| ATOM | 3668 | CD1 | LEU | B | 555 | 41.208 | 50.115 | 66.793 | 1.00 | 19.52 | B | C |
| ATOM | 3669 | CD2 | LEU | B | 555 | 39.390 | 51.363 | 65.633 | 1.00 | 18.83 | B | C |
| ATOM | 3670 | C | LEU | B | 555 | 39.103 | 49.891 | 69.773 | 1.00 | 18.84 | B | C |
| ATOM | 3671 | O | LEU | B | 555 | 40.203 | 50.245 | 70.191 | 1.00 | 17.34 | B | O |
| ATOM | 3672 | N | ASN | B | 556 | 37.959 | 50.362 | 70.261 | 1.00 | 20.25 | B | N |
| ATOM | 3673 | CA | ASN | B | 556 | 37.927 | 51.336 | 71.342 | 1.00 | 19.57 | B | C |
| ATOM | 3674 | CB | ASN | B | 556 | 36.507 | 51.886 | 71.502 | 1.00 | 18.53 | B | C |
| ATOM | 3675 | CG | ASN | B | 556 | 36.189 | 52.995 | 70.497 | 1.00 | 18.58 | B | C |
| ATOM | 3676 | OD1 | ASN | B | 556 | 37.090 | 53.578 | 69.884 | 1.00 | 15.73 | B | O |
| ATOM | 3677 | ND2 | ASN | B | 556 | 34.903 | 53.295 | 70.333 | 1.00 | 14.09 | B | N |
| ATOM | 3678 | C | ASN | B | 556 | 38.412 | 50.719 | 72.655 | 1.00 | 19.40 | B | C |
| ATOM | 3679 | O | ASN | B | 556 | 39.074 | 51.382 | 73.447 | 1.00 | 17.65 | B | O |
| ATOM | 3680 | N | SER | B | 557 | 38.086 | 49.450 | 72.877 | 1.00 | 21.14 | B | N |
| ATOM | 3681 | CA | SER | B | 557 | 38.513 | 48.751 | 74.083 | 1.00 | 24.69 | B | C |
| ATOM | 3682 | CB | SER | B | 557 | 37.931 | 47.340 | 74.126 | 1.00 | 24.57 | B | C |
| ATOM | 3683 | OG | SER | B | 557 | 36.528 | 47.382 | 74.309 | 1.00 | 28.76 | B | O |
| ATOM | 3684 | C | SER | B | 557 | 40.027 | 48.654 | 74.076 | 1.00 | 26.40 | B | C |
| ATOM | 3685 | O | SER | B | 557 | 40.690 | 48.944 | 75.073 | 1.00 | 28.99 | B | O |
| ATOM | 3686 | N | LEU | B | 558 | 40.567 | 48.243 | 72.937 | 1.00 | 26.57 | B | N |
| ATOM | 3687 | CA | LEU | B | 558 | 42.004 | 48.104 | 72.778 | 1.00 | 26.68 | B | C |
| ATOM | 3688 | CB | LEU | B | 558 | 42.321 | 47.543 | 71.388 | 1.00 | 26.27 | B | C |
| ATOM | 3689 | CG | LEU | B | 558 | 43.798 | 47.448 | 71.005 | 1.00 | 28.47 | B | C |
| ATOM | 3690 | CD1 | LEU | B | 558 | 44.545 | 46.628 | 72.045 | 1.00 | 28.67 | B | C |
| ATOM | 3691 | CD2 | LEU | B | 558 | 43.929 | 46.809 | 69.636 | 1.00 | 28.89 | B | C |
| ATOM | 3692 | C | LEU | B | 558 | 42.738 | 49.429 | 72.985 | 1.00 | 26.76 | B | C |
| ATOM | 3693 | O | LEU | B | 558 | 43.704 | 49.490 | 73.739 | 1.00 | 29.13 | B | O |
| ATOM | 3694 | N | ARG | B | 559 | 42.276 | 50.486 | 72.329 | 1.00 | 25.75 | B | N |
| ATOM | 3695 | CA | ARG | B | 559 | 42.920 | 51.792 | 72.440 | 1.00 | 25.17 | B | C |
| ATOM | 3696 | CB | ARG | B | 559 | 42.379 | 52.740 | 71.363 | 1.00 | 22.82 | B | C |
| ATOM | 3697 | CG | ARG | B | 559 | 43.102 | 52.607 | 70.022 | 1.00 | 21.54 | B | C |
| ATOM | 3698 | CD | ARG | B | 559 | 42.491 | 53.496 | 68.955 | 1.00 | 17.67 | B | C |
| ATOM | 3699 | NE | ARG | B | 559 | 43.169 | 54.783 | 68.843 | 1.00 | 15.45 | B | N |
| ATOM | 3700 | CZ | ARG | B | 559 | 44.330 | 54.964 | 68.223 | 1.00 | 16.95 | B | C |
| ATOM | 3701 | NH1 | ARG | B | 559 | 44.945 | 53.934 | 67.658 | 1.00 | 17.97 | B | N |
| ATOM | 3702 | NH2 | ARG | B | 559 | 44.871 | 56.173 | 68.154 | 1.00 | 14.12 | B | N |
| ATOM | 3703 | C | ARG | B | 559 | 42.763 | 52.428 | 73.813 | 1.00 | 26.58 | B | C |
| ATOM | 3704 | O | ARG | B | 559 | 43.636 | 53.176 | 74.262 | 1.00 | 26.33 | B | O |
| ATOM | 3705 | N | LYS | B | 560 | 41.647 | 52.142 | 74.478 | 1.00 | 28.73 | B | N |
| ATOM | 3706 | CA | LYS | B | 560 | 41.402 | 52.688 | 75.808 | 1.00 | 30.60 | B | C |
| ATOM | 3707 | CB | LYS | B | 560 | 40.020 | 52.259 | 76.318 | 1.00 | 30.82 | B | C |
| ATOM | 3708 | CG | LYS | B | 560 | 39.731 | 52.636 | 77.769 | 1.00 | 32.36 | B | C |
| ATOM | 3709 | CD | LYS | B | 560 | 39.291 | 54.089 | 77.900 | 1.00 | 35.24 | B | C |
| ATOM | 3710 | CE | LYS | B | 560 | 38.817 | 54.413 | 79.319 | 1.00 | 36.11 | B | C |
| ATOM | 3711 | NZ | LYS | B | 560 | 37.753 | 55.469 | 79.357 | 1.00 | 34.73 | B | N |
| ATOM | 3712 | C | LYS | B | 560 | 42.490 | 52.151 | 76.732 | 1.00 | 31.08 | B | C |
| ATOM | 3713 | O | LYS | B | 560 | 43.156 | 52.910 | 77.436 | 1.00 | 31.95 | B | O |
| ATOM | 3714 | N | GLU | B | 561 | 42.673 | 50.837 | 76.704 | 1.00 | 31.70 | B | N |
| ATOM | 3715 | CA | GLU | B | 561 | 43.677 | 50.185 | 77.526 | 1.00 | 34.14 | B | C |
| ATOM | 3716 | CB | GLU | B | 561 | 43.604 | 48.674 | 77.329 | 1.00 | 37.38 | B | C |
| ATOM | 3717 | CG | GLU | B | 561 | 42.785 | 47.964 | 78.394 | 1.00 | 44.15 | B | C |
| ATOM | 3718 | CD | GLU | B | 561 | 42.823 | 46.453 | 78.243 | 1.00 | 48.94 | B | C |
| ATOM | 3719 | OE1 | GLU | B | 561 | 43.902 | 45.910 | 77.908 | 1.00 | 51.51 | B | O |
| ATOM | 3720 | OE2 | GLU | B | 561 | 41.773 | 45.806 | 78.459 | 1.00 | 51.09 | B | O |
| ATOM | 3721 | C | GLU | B | 561 | 45.096 | 50.678 | 77.236 | 1.00 | 33.16 | B | C |
| ATOM | 3722 | O | GLU | B | 561 | 45.925 | 50.740 | 78.142 | 1.00 | 35.62 | B | O |
| ATOM | 3723 | N | ARG | B | 562 | 45.379 | 51.026 | 75.983 | 1.00 | 30.50 | B | N |
| ATOM | 3724 | CA | ARG | B | 562 | 46.707 | 51.509 | 75.614 | 1.00 | 28.20 | B | C |
| ATOM | 3725 | CB | ARG | B | 562 | 46.940 | 51.363 | 74.105 | 1.00 | 27.96 | B | C |
| ATOM | 3726 | CG | ARG | B | 562 | 46.786 | 49.944 | 73.562 | 1.00 | 27.78 | B | C |
| ATOM | 3727 | CD | ARG | B | 562 | 47.966 | 49.552 | 72.685 | 1.00 | 28.68 | B | C |
| ATOM | 3728 | NE | ARG | B | 562 | 49.246 | 49.832 | 73.335 | 1.00 | 29.96 | B | N |
| ATOM | 3729 | CZ | ARG | B | 562 | 50.435 | 49.730 | 72.745 | 1.00 | 32.70 | B | C |
| ATOM | 3730 | NH1 | ARG | B | 562 | 50.532 | 49.352 | 71.477 | 1.00 | 33.55 | B | N |
| ATOM | 3731 | NH2 | ARG | B | 562 | 51.535 | 50.011 | 73.427 | 1.00 | 34.51 | B | N |
| ATOM | 3732 | C | ARG | B | 562 | 46.861 | 52.971 | 76.001 | 1.00 | 27.58 | B | C |
| ATOM | 3733 | O | ARG | B | 562 | 47.951 | 53.531 | 75.929 | 1.00 | 27.60 | B | O |
| ATOM | 3734 | N | GLY | B | 563 | 45.760 | 53.588 | 76.412 | 1.00 | 27.63 | B | N |
| ATOM | 3735 | CA | GLY | B | 563 | 45.805 | 54.988 | 76.784 | 1.00 | 26.88 | B | C |
| ATOM | 3736 | C | GLY | B | 563 | 45.693 | 55.892 | 75.566 | 1.00 | 28.10 | B | C |
| ATOM | 3737 | O | GLY | B | 563 | 46.044 | 57.078 | 75.626 | 1.00 | 29.09 | B | O |
| ATOM | 3738 | N | MET | B | 564 | 45.201 | 55.333 | 74.458 | 1.00 | 26.66 | B | N |
| ATOM | 3739 | CA | MET | B | 564 | 45.042 | 56.084 | 73.213 | 1.00 | 25.17 | B | C |
| ATOM | 3740 | CB | MET | B | 564 | 45.344 | 55.184 | 72.011 | 1.00 | 24.47 | B | C |
| ATOM | 3741 | CG | MET | B | 564 | 46.812 | 54.852 | 71.826 | 1.00 | 25.52 | B | C |
| ATOM | 3742 | SD | MET | B | 564 | 47.063 | 53.372 | 70.820 | 1.00 | 26.52 | B | S |
| ATOM | 3743 | CE | MET | B | 564 | 48.702 | 53.682 | 70.204 | 1.00 | 26.56 | B | C |
| ATOM | 3744 | C | MET | B | 564 | 43.623 | 56.633 | 73.094 | 1.00 | 24.00 | B | C |
| ATOM | 3745 | O | MET | B | 564 | 42.753 | 56.287 | 73.890 | 1.00 | 24.84 | B | O |
| ATOM | 3746 | N | ASN | B | 565 | 43.391 | 57.486 | 72.100 | 1.00 | 22.62 | B | N |
| ATOM | 3747 | CA | ASN | B | 565 | 42.067 | 58.067 | 71.893 | 1.00 | 21.36 | B | C |
| ATOM | 3748 | CB | ASN | B | 565 | 42.152 | 59.296 | 70.972 | 1.00 | 21.82 | B | C |
| ATOM | 3749 | CG | ASN | B | 565 | 42.771 | 58.986 | 69.616 | 1.00 | 21.34 | B | C |
| ATOM | 3750 | OD1 | ASN | B | 565 | 43.902 | 58.514 | 69.524 | 1.00 | 21.84 | B | O |
| ATOM | 3751 | ND2 | ASN | B | 565 | 42.025 | 59.263 | 68.554 | 1.00 | 20.03 | B | N |
| ATOM | 3752 | C | ASN | B | 565 | 41.109 | 57.037 | 71.308 | 1.00 | 20.02 | B | C |
| ATOM | 3753 | O | ASN | B | 565 | 41.537 | 56.054 | 70.711 | 1.00 | 20.66 | B | O |
| ATOM | 3754 | N | THR | B | 566 | 39.813 | 57.249 | 71.505 | 1.00 | 18.47 | B | N |
| ATOM | 3755 | CA | THR | B | 566 | 38.812 | 56.331 | 70.989 | 1.00 | 16.81 | B | C |
| ATOM | 3756 | CB | THR | B | 566 | 37.928 | 55.766 | 72.128 | 1.00 | 17.38 | B | C |
| ATOM | 3757 | OG1 | THR | B | 566 | 37.344 | 56.842 | 72.868 | 1.00 | 18.40 | B | O |
| ATOM | 3758 | CG2 | THR | B | 566 | 38.763 | 54.913 | 73.068 | 1.00 | 16.87 | B | C |
| ATOM | 3759 | C | THR | B | 566 | 37.956 | 57.063 | 69.954 | 1.00 | 16.06 | B | C |
| ATOM | 3760 | O | THR | B | 566 | 38.074 | 58.277 | 69.802 | 1.00 | 17.41 | B | O |
| ATOM | 3761 | N | PHE | B | 567 | 37.094 | 56.336 | 69.247 | 1.00 | 15.55 | B | N |
| ATOM | 3762 | CA | PHE | B | 567 | 36.275 | 56.949 | 68.202 | 1.00 | 14.50 | B | C |
| ATOM | 3763 | CB | PHE | B | 567 | 36.652 | 56.375 | 66.827 | 1.00 | 13.97 | B | C |
| ATOM | 3764 | CG | PHE | B | 567 | 38.132 | 56.245 | 66.603 | 1.00 | 10.94 | B | C |
| ATOM | 3765 | CD1 | PHE | B | 567 | 38.902 | 57.359 | 66.283 | 1.00 | 12.04 | B | C |
| ATOM | 3766 | CD2 | PHE | B | 567 | 38.758 | 55.014 | 66.731 | 1.00 | 10.99 | B | C |
| ATOM | 3767 | CE1 | PHE | B | 567 | 40.280 | 57.249 | 66.096 | 1.00 | 10.96 | B | C |
| ATOM | 3768 | CE2 | PHE | B | 567 | 40.138 | 54.890 | 66.547 | 1.00 | 11.68 | B | C |
| ATOM | 3769 | CZ | PHE | B | 567 | 40.899 | 56.007 | 66.230 | 1.00 | 10.30 | B | C |
| ATOM | 3770 | C | PHE | B | 567 | 34.776 | 56.805 | 68.378 | 1.00 | 14.49 | B | C |
| ATOM | 3771 | O | PHE | B | 567 | 34.292 | 55.836 | 68.956 | 1.00 | 14.21 | B | O |
| ATOM | 3772 | N | LEU | B | 568 | 34.044 | 57.781 | 67.856 | 1.00 | 14.30 | B | N |
| ATOM | 3773 | CA | LEU | B | 568 | 32.594 | 57.760 | 67.926 | 1.00 | 15.02 | B | C |
| ATOM | 3774 | CB | LEU | B | 568 | 32.059 | 59.171 | 68.196 | 1.00 | 13.98 | B | C |
| ATOM | 3775 | CG | LEU | B | 568 | 32.445 | 59.839 | 69.521 | 1.00 | 14.58 | B | C |
| ATOM | 3776 | CD1 | LEU | B | 568 | 31.774 | 61.188 | 69.609 | 1.00 | 12.34 | B | C |
| ATOM | 3777 | CD2 | LEU | B | 568 | 32.019 | 58.973 | 70.696 | 1.00 | 12.24 | B | C |
| ATOM | 3778 | C | LEU | B | 568 | 32.052 | 57.257 | 66.591 | 1.00 | 15.69 | B | C |
| ATOM | 3779 | O | LEU | B | 568 | 32.735 | 57.338 | 65.571 | 1.00 | 16.80 | B | O |
| ATOM | 3780 | N | PHE | B | 569 | 30.835 | 56.720 | 66.606 | 1.00 | 15.75 | B | N |
| ATOM | 3781 | CA | PHE | B | 569 | 30.182 | 56.245 | 65.393 | 1.00 | 14.11 | B | C |
| ATOM | 3782 | CB | PHE | B | 569 | 29.651 | 54.819 | 65.597 | 1.00 | 14.41 | B | C |
| ATOM | 3783 | CG | PHE | B | 569 | 28.967 | 54.232 | 64.386 | 1.00 | 13.95 | B | C |
| ATOM | 3784 | CD1 | PHE | B | 569 | 29.473 | 54.443 | 63.103 | 1.00 | 15.56 | B | C |
| ATOM | 3785 | CD2 | PHE | B | 569 | 27.811 | 53.468 | 64.530 | 1.00 | 13.48 | B | C |
| ATOM | 3786 | CE1 | PHE | B | 569 | 28.830 | 53.897 | 61.975 | 1.00 | 13.25 | B | C |
| ATOM | 3787 | CE2 | PHE | B | 569 | 27.162 | 52.919 | 63.417 | 1.00 | 14.36 | B | C |
| ATOM | 3788 | CZ | PHE | B | 569 | 27.675 | 53.136 | 62.134 | 1.00 | 13.09 | B | C |
| ATOM | 3789 | C | PHE | B | 569 | 29.035 | 57.231 | 65.157 | 1.00 | 15.17 | B | C |
| ATOM | 3790 | O | PHE | B | 569 | 28.087 | 57.286 | 65.943 | 1.00 | 15.24 | B | O |
| ATOM | 3791 | N | ARG | B | 570 | 29.143 | 58.028 | 64.093 | 1.00 | 14.79 | B | N |
| ATOM | 3792 | CA | ARG | B | 570 | 28.136 | 59.040 | 63.750 | 1.00 | 13.97 | B | C |
| ATOM | 3793 | CB | ARG | B | 570 | 28.711 | 60.436 | 64.019 | 1.00 | 12.55 | B | C |
| ATOM | 3794 | CG | ARG | B | 570 | 29.358 | 60.586 | 65.390 | 1.00 | 11.75 | B | C |
| ATOM | 3795 | CD | ARG | B | 570 | 30.281 | 61.787 | 65.463 | 1.00 | 9.43 | B | C |
| ATOM | 3796 | NE | ARG | B | 570 | 29.620 | 63.020 | 65.042 | 1.00 | 8.17 | B | N |
| ATOM | 3797 | CZ | ARG | B | 570 | 30.173 | 64.230 | 65.101 | 1.00 | 8.32 | B | C |
| ATOM | 3798 | NH1 | ARG | B | 570 | 31.404 | 64.383 | 65.567 | 1.00 | 8.84 | B | N |
| ATOM | 3799 | NH2 | ARG | B | 570 | 29.504 | 65.293 | 64.672 | 1.00 | 6.62 | B | N |
| ATOM | 3800 | C | ARG | B | 570 | 27.722 | 58.920 | 62.277 | 1.00 | 14.51 | B | C |
| ATOM | 3801 | O | ARG | B | 570 | 28.177 | 59.684 | 61.426 | 1.00 | 13.61 | B | O |
| ATOM | 3802 | N | PRO | B | 571 | 26.823 | 57.971 | 61.964 | 1.00 | 14.97 | B | N |
| ATOM | 3803 | CD | PRO | B | 571 | 26.156 | 57.054 | 62.910 | 1.00 | 14.29 | B | C |
| ATOM | 3804 | CA | PRO | B | 571 | 26.359 | 57.749 | 60.589 | 1.00 | 13.57 | B | C |
| ATOM | 3805 | CB | PRO | B | 571 | 25.835 | 56.322 | 60.630 | 1.00 | 12.39 | B | C |
| ATOM | 3806 | CG | PRO | B | 571 | 25.254 | 56.218 | 62.007 | 1.00 | 11.78 | B | C |
| ATOM | 3807 | C | PRO | B | 571 | 25.282 | 58.700 | 60.080 | 1.00 | 15.10 | B | C |
| ATOM | 3808 | O | PRO | B | 571 | 24.624 | 59.397 | 60.857 | 1.00 | 15.40 | B | O |
| ATOM | 3809 | N | HIS | B | 572 | 25.122 | 58.728 | 58.760 | 1.00 | 14.46 | B | N |
| ATOM | 3810 | CA | HIS | B | 572 | 24.082 | 59.528 | 58.136 | 1.00 | 13.08 | B | C |
| ATOM | 3811 | CB | HIS | B | 572 | 24.313 | 59.623 | 56.630 | 1.00 | 13.41 | B | C |
| ATOM | 3812 | CG | HIS | B | 572 | 25.159 | 60.790 | 56.215 | 1.00 | 11.30 | B | C |
| ATOM | 3813 | CD2 | HIS | B | 572 | 24.925 | 61.792 | 55.336 | 1.00 | 11.36 | B | C |
| ATOM | 3814 | ND1 | HIS | B | 572 | 26.421 | 61.009 | 56.726 | 1.00 | 10.43 | B | N |
| ATOM | 3815 | CE1 | HIS | B | 572 | 26.928 | 62.102 | 56.177 | 1.00 | 13.89 | B | C |
| ATOM | 3816 | NE2 | HIS | B | 572 | 26.038 | 62.594 | 55.328 | 1.00 | 10.19 | B | N |
| ATOM | 3817 | C | HIS | B | 572 | 22.887 | 58.631 | 58.432 | 1.00 | 12.79 | B | C |
| ATOM | 3818 | O | HIS | B | 572 | 22.976 | 57.418 | 58.252 | 1.00 | 13.14 | B | O |
| ATOM | 3819 | N | CYS | B | 573 | 21.783 | 59.204 | 58.893 | 1.00 | 11.52 | B | N |
| ATOM | 3820 | CA | CYS | B | 573 | 20.637 | 58.376 | 59.242 | 1.00 | 12.52 | B | C |
| ATOM | 3821 | CB | CYS | B | 573 | 20.864 | 57.764 | 60.627 | 1.00 | 12.75 | B | C |
| ATOM | 3822 | SG | CYS | B | 573 | 19.616 | 56.575 | 61.166 | 1.00 | 14.82 | B | S |
| ATOM | 3823 | C | CYS | B | 573 | 19.331 | 59.146 | 59.240 | 1.00 | 13.76 | B | C |
| ATOM | 3824 | O | CYS | B | 573 | 19.257 | 60.275 | 59.739 | 1.00 | 13.63 | B | O |
| ATOM | 3825 | N | GLY | B | 574 | 18.301 | 58.529 | 58.667 | 1.00 | 14.08 | B | N |
| ATOM | 3826 | CA | GLY | B | 574 | 16.991 | 59.154 | 58.622 | 1.00 | 14.00 | B | C |
| ATOM | 3827 | C | GLY | B | 574 | 16.743 | 60.176 | 57.528 | 1.00 | 15.22 | B | C |
| ATOM | 3828 | O | GLY | B | 574 | 15.714 | 60.850 | 57.544 | 1.00 | 15.22 | B | O |
| ATOM | 3829 | N | GLU | B | 575 | 17.674 | 60.316 | 56.590 | 1.00 | 16.47 | B | N |
| ATOM | 3830 | CA | GLU | B | 575 | 17.489 | 61.266 | 55.493 | 1.00 | 16.74 | B | C |
| ATOM | 3831 | CB | GLU | B | 575 | 18.763 | 61.398 | 54.673 | 1.00 | 16.43 | B | C |
| ATOM | 3832 | CG | GLU | B | 575 | 18.731 | 62.549 | 53.695 | 1.00 | 16.49 | B | C |
| ATOM | 3833 | CD | GLU | B | 575 | 20.027 | 62.673 | 52.932 | 1.00 | 15.85 | B | C |
| ATOM | 3834 | OE1 | GLU | B | 575 | 20.344 | 63.783 | 52.464 | 1.00 | 21.33 | B | O |
| ATOM | 3835 | OE2 | GLU | B | 575 | 20.734 | 61.657 | 52.799 | 1.00 | 15.07 | B | O |
| ATOM | 3836 | C | GLU | B | 575 | 16.369 | 60.746 | 54.605 | 1.00 | 16.98 | B | C |
| ATOM | 3837 | O | GLU | B | 575 | 15.618 | 61.523 | 54.023 | 1.00 | 16.59 | B | O |
| ATOM | 3838 | N | VAL | B | 576 | 16.276 | 59.422 | 54.515 | 1.00 | 17.20 | B | N |
| ATOM | 3839 | CA | VAL | B | 576 | 15.249 | 58.739 | 53.734 | 1.00 | 20.30 | B | C |
| ATOM | 3840 | CB | VAL | B | 576 | 15.401 | 58.978 | 52.217 | 1.00 | 22.68 | B | C |
| ATOM | 3841 | CG1 | VAL | B | 576 | 14.550 | 60.168 | 51.791 | 1.00 | 27.36 | B | C |
| ATOM | 3842 | CG2 | VAL | B | 576 | 16.858 | 59.200 | 51.866 | 1.00 | 27.18 | B | C |
| ATOM | 3843 | C | VAL | B | 576 | 15.388 | 57.250 | 53.995 | 1.00 | 20.22 | B | C |
| ATOM | 3844 | O | VAL | B | 576 | 16.225 | 56.835 | 54.791 | 1.00 | 21.34 | B | O |
| ATOM | 3845 | N | GLY | B | 577 | 14.571 | 56.443 | 53.330 | 1.00 | 19.85 | B | N |
| ATOM | 3846 | CA | GLY | B | 577 | 14.661 | 55.012 | 53.537 | 1.00 | 19.36 | B | C |
| ATOM | 3847 | C | GLY | B | 577 | 13.774 | 54.522 | 54.664 | 1.00 | 19.91 | B | C |
| ATOM | 3848 | O | GLY | B | 577 | 12.889 | 55.243 | 55.120 | 1.00 | 17.64 | B | O |
| ATOM | 3849 | N | ALA | B | 578 | 14.024 | 53.291 | 55.112 | 1.00 | 19.71 | B | N |
| ATOM | 3850 | CA | ALA | B | 578 | 13.251 | 52.659 | 56.179 | 1.00 | 20.78 | B | C |
| ATOM | 3851 | CB | ALA | B | 578 | 13.549 | 51.163 | 56.207 | 1.00 | 19.55 | B | C |
| ATOM | 3852 | C | ALA | B | 578 | 13.486 | 53.259 | 57.565 | 1.00 | 21.39 | B | C |
| ATOM | 3853 | O | ALA | B | 578 | 14.558 | 53.785 | 57.857 | 1.00 | 20.97 | B | O |
| ATOM | 3854 | N | LEU | B | 579 | 12.470 | 53.169 | 58.417 | 1.00 | 23.82 | B | N |
| ATOM | 3855 | CA | LEU | B | 579 | 12.561 | 53.692 | 59.782 | 1.00 | 25.78 | B | C |
| ATOM | 3856 | CB | LEU | B | 579 | 11.204 | 53.617 | 60.479 | 1.00 | 25.26 | B | C |
| ATOM | 3857 | CG | LEU | B | 579 | 10.230 | 54.760 | 60.226 | 1.00 | 24.73 | B | C |
| ATOM | 3858 | CD1 | LEU | B | 579 | 8.905 | 54.431 | 60.871 | 1.00 | 25.72 | B | C |
| ATOM | 3859 | CD2 | LEU | B | 579 | 10.796 | 56.051 | 60.783 | 1.00 | 27.93 | B | C |
| ATOM | 3860 | C | LEU | B | 579 | 13.565 | 52.881 | 60.586 | 1.00 | 25.66 | B | C |
| ATOM | 3861 | O | LEU | B | 579 | 14.199 | 53.393 | 61.508 | 1.00 | 26.10 | B | O |
| ATOM | 3862 | N | THR | B | 580 | 13.703 | 51.609 | 60.227 | 1.00 | 24.94 | B | N |
| ATOM | 3863 | CA | THR | B | 580 | 14.624 | 50.725 | 60.916 | 1.00 | 24.14 | B | C |
| ATOM | 3864 | CB | THR | B | 580 | 14.660 | 49.338 | 60.248 | 1.00 | 25.45 | B | C |
| ATOM | 3865 | OG1 | THR | B | 580 | 15.179 | 49.453 | 58.917 | 1.00 | 29.39 | B | O |
| ATOM | 3866 | CG2 | THR | B | 580 | 13.261 | 48.755 | 60.183 | 1.00 | 26.26 | B | C |
| ATOM | 3867 | C | THR | B | 580 | 16.033 | 51.299 | 60.964 | 1.00 | 22.96 | B | C |
| ATOM | 3868 | O | THR | B | 580 | 16.857 | 50.837 | 61.741 | 1.00 | 24.60 | B | O |
| ATOM | 3869 | N | HIS | B | 581 | 16.313 | 52.301 | 60.134 | 1.00 | 21.08 | B | N |
| ATOM | 3870 | CA | HIS | B | 581 | 17.635 | 52.922 | 60.120 | 1.00 | 18.84 | B | C |
| ATOM | 3871 | CB | HIS | B | 581 | 17.807 | 53.857 | 58.917 | 1.00 | 18.72 | B | C |
| ATOM | 3872 | CG | HIS | B | 581 | 17.830 | 53.159 | 57.596 | 1.00 | 19.48 | B | C |
| ATOM | 3873 | CD2 | HIS | B | 581 | 17.623 | 51.863 | 57.264 | 1.00 | 18.84 | B | C |
| ATOM | 3874 | ND1 | HIS | B | 581 | 18.056 | 53.826 | 56.413 | 1.00 | 19.97 | B | N |
| ATOM | 3875 | CE1 | HIS | B | 581 | 17.986 | 52.971 | 55.408 | 1.00 | 20.52 | B | C |
| ATOM | 3876 | NE2 | HIS | B | 581 | 17.724 | 51.773 | 55.898 | 1.00 | 19.90 | B | N |
| ATOM | 3877 | C | HIS | B | 581 | 17.816 | 53.750 | 61.381 | 1.00 | 17.62 | B | C |
| ATOM | 3878 | O | HIS | B | 581 | 18.916 | 53.840 | 61.916 | 1.00 | 18.06 | B | O |
| ATOM | 3879 | N | LEU | B | 582 | 16.732 | 54.370 | 61.839 | 1.00 | 15.83 | B | N |
| ATOM | 3880 | CA | LEU | B | 582 | 16.790 | 55.216 | 63.023 | 1.00 | 16.27 | B | C |
| ATOM | 3881 | CB | LEU | B | 582 | 15.616 | 56.201 | 63.020 | 1.00 | 13.97 | B | C |
| ATOM | 3882 | CG | LEU | B | 582 | 15.794 | 57.331 | 61.991 | 1.00 | 13.23 | B | C |
| ATOM | 3883 | CD1 | LEU | B | 582 | 14.451 | 57.903 | 61.590 | 1.00 | 11.99 | B | C |
| ATOM | 3884 | CD2 | LEU | B | 582 | 16.686 | 58.419 | 62.566 | 1.00 | 11.69 | B | C |
| ATOM | 3885 | C | LEU | B | 582 | 16.803 | 54.375 | 64.289 | 1.00 | 17.17 | B | C |
| ATOM | 3886 | O | LEU | B | 582 | 17.331 | 54.785 | 65.325 | 1.00 | 18.20 | B | O |
| ATOM | 3887 | N | MET | B | 583 | 16.236 | 53.181 | 64.190 | 1.00 | 17.43 | B | N |
| ATOM | 3888 | CA | MET | B | 583 | 16.198 | 52.265 | 65.310 | 1.00 | 18.64 | B | C |
| ATOM | 3889 | CB | MET | B | 583 | 15.194 | 51.156 | 65.014 | 1.00 | 22.26 | B | C |
| ATOM | 3890 | CG | MET | B | 583 | 15.088 | 50.100 | 66.086 | 1.00 | 26.95 | B | C |
| ATOM | 3891 | SD | MET | B | 583 | 15.563 | 48.498 | 65.438 | 1.00 | 36.22 | B | S |
| ATOM | 3892 | CE | MET | B | 583 | 17.300 | 48.533 | 65.735 | 1.00 | 31.52 | B | C |
| ATOM | 3893 | C | MET | B | 583 | 17.597 | 51.689 | 65.531 | 1.00 | 18.39 | B | C |
| ATOM | 3894 | O | MET | B | 583 | 18.050 | 51.552 | 66.668 | 1.00 | 16.95 | B | O |
| ATOM | 3895 | N | THR | B | 584 | 18.283 | 51.369 | 64.436 | 1.00 | 15.75 | B | N |
| ATOM | 3896 | CA | THR | B | 584 | 19.626 | 50.806 | 64.503 | 1.00 | 13.95 | B | C |
| ATOM | 3897 | CB | THR | B | 584 | 20.076 | 50.287 | 63.107 | 1.00 | 13.76 | B | C |
| ATOM | 3898 | OG1 | THR | B | 584 | 19.209 | 49.226 | 62.700 | 1.00 | 12.05 | B | O |
| ATOM | 3899 | CG2 | THR | B | 584 | 21.492 | 49.746 | 63.151 | 1.00 | 13.91 | B | C |
| ATOM | 3900 | C | THR | B | 584 | 20.627 | 51.834 | 65.031 | 1.00 | 14.59 | B | C |
| ATOM | 3901 | O | THR | B | 584 | 21.597 | 51.477 | 65.709 | 1.00 | 14.88 | B | O |
| ATOM | 3902 | N | ALA | B | 585 | 20.396 | 53.107 | 64.721 | 1.00 | 13.57 | B | N |
| ATOM | 3903 | CA | ALA | B | 585 | 21.274 | 54.168 | 65.194 | 1.00 | 13.43 | B | C |
| ATOM | 3904 | CB | ALA | B | 585 | 21.006 | 55.450 | 64.437 | 1.00 | 13.24 | B | C |
| ATOM | 3905 | C | ALA | B | 585 | 21.041 | 54.383 | 66.691 | 1.00 | 13.19 | B | C |
| ATOM | 3906 | O | ALA | B | 585 | 21.953 | 54.771 | 67.422 | 1.00 | 12.17 | B | O |
| ATOM | 3907 | N | PHE | B | 586 | 19.813 | 54.139 | 67.136 | 1.00 | 14.32 | B | N |
| ATOM | 3908 | CA | PHE | B | 586 | 19.472 | 54.283 | 68.548 | 1.00 | 15.63 | B | C |
| ATOM | 3909 | CB | PHE | B | 586 | 17.985 | 53.993 | 68.778 | 1.00 | 15.71 | B | C |
| ATOM | 3910 | CG | PHE | B | 586 | 17.565 | 54.058 | 70.229 | 1.00 | 18.67 | B | C |
| ATOM | 3911 | CD1 | PHE | B | 586 | 17.299 | 55.284 | 70.838 | 1.00 | 19.18 | B | C |
| ATOM | 3912 | CD2 | PHE | B | 586 | 17.448 | 52.894 | 70.986 | 1.00 | 18.01 | B | C |
| ATOM | 3913 | CE1 | PHE | B | 586 | 16.925 | 55.346 | 72.177 | 1.00 | 19.19 | B | C |
| ATOM | 3914 | CE2 | PHE | B | 586 | 17.075 | 52.942 | 72.322 | 1.00 | 17.28 | B | C |
| ATOM | 3915 | CZ | PHE | B | 586 | 16.812 | 54.168 | 72.922 | 1.00 | 17.69 | B | C |
| ATOM | 3916 | C | PHE | B | 586 | 20.321 | 53.294 | 69.352 | 1.00 | 16.12 | B | C |
| ATOM | 3917 | O | PHE | B | 586 | 20.750 | 53.598 | 70.462 | 1.00 | 17.26 | B | O |
| ATOM | 3918 | N | MET | B | 587 | 20.577 | 52.126 | 68.767 | 1.00 | 14.53 | B | N |
| ATOM | 3919 | CA | MET | B | 587 | 21.376 | 51.084 | 69.408 | 1.00 | 15.31 | B | C |
| ATOM | 3920 | CB | MET | B | 587 | 21.023 | 49.696 | 68.850 | 1.00 | 13.30 | B | C |
| ATOM | 3921 | CG | MET | B | 587 | 19.574 | 49.284 | 68.921 | 1.00 | 15.37 | B | C |
| ATOM | 3922 | SD | MET | B | 587 | 19.320 | 47.625 | 68.216 | 1.00 | 19.92 | B | S |
| ATOM | 3923 | CE | MET | B | 587 | 20.411 | 46.609 | 69.258 | 1.00 | 14.39 | B | C |
| ATOM | 3924 | C | MET | B | 587 | 22.886 | 51.225 | 69.254 | 1.00 | 15.31 | B | C |
| ATOM | 3925 | O | MET | B | 587 | 23.634 | 50.796 | 70.130 | 1.00 | 16.67 | B | O |
| ATOM | 3926 | N | THR | B | 588 | 23.335 | 51.825 | 68.153 | 1.00 | 14.64 | B | N |
| ATOM | 3927 | CA | THR | B | 588 | 24.769 | 51.884 | 67.859 | 1.00 | 13.98 | B | C |
| ATOM | 3928 | CB | THR | B | 588 | 25.059 | 51.103 | 66.557 | 1.00 | 14.77 | B | C |
| ATOM | 3929 | OG1 | THR | B | 588 | 24.316 | 51.702 | 65.485 | 1.00 | 15.27 | B | O |
| ATOM | 3930 | CG2 | THR | B | 588 | 24.641 | 49.647 | 66.681 | 1.00 | 11.92 | B | C |
| ATOM | 3931 | C | THR | B | 588 | 25.516 | 53.198 | 67.710 | 1.00 | 12.35 | B | C |
| ATOM | 3932 | O | THR | B | 588 | 26.749 | 53.200 | 67.730 | 1.00 | 11.32 | B | O |
| ATOM | 3933 | N | ALA | B | 589 | 24.810 | 54.309 | 67.557 | 1.00 | 13.79 | B | N |
| ATOM | 3934 | CA | ALA | B | 589 | 25.504 | 55.574 | 67.335 | 1.00 | 13.85 | B | C |
| ATOM | 3935 | CB | ALA | B | 589 | 25.012 | 56.182 | 66.018 | 1.00 | 13.64 | B | C |
| ATOM | 3936 | C | ALA | B | 589 | 25.466 | 56.636 | 68.428 | 1.00 | 12.99 | B | C |
| ATOM | 3937 | O | ALA | B | 589 | 24.457 | 56.822 | 69.096 | 1.00 | 14.44 | B | O |
| ATOM | 3938 | N | ASP | B | 590 | 26.581 | 57.344 | 68.582 | 1.00 | 14.11 | B | N |
| ATOM | 3939 | CA | ASP | B | 590 | 26.694 | 58.424 | 69.553 | 1.00 | 16.04 | B | C |
| ATOM | 3940 | CB | ASP | B | 590 | 28.122 | 58.968 | 69.559 | 1.00 | 16.23 | B | C |
| ATOM | 3941 | CG | ASP | B | 590 | 28.349 | 60.002 | 70.646 | 1.00 | 18.78 | B | C |
| ATOM | 3942 | OD1 | ASP | B | 590 | 28.187 | 61.206 | 70.359 | 1.00 | 19.14 | B | O |
| ATOM | 3943 | OD2 | ASP | B | 590 | 28.698 | 59.617 | 71.785 | 1.00 | 19.08 | B | O |
| ATOM | 3944 | C | ASP | B | 590 | 25.712 | 59.523 | 69.132 | 1.00 | 18.17 | B | C |
| ATOM | 3945 | O | ASP | B | 590 | 24.922 | 60.012 | 69.935 | 1.00 | 19.41 | B | O |
| ATOM | 3946 | N | ASN | B | 591 | 25.777 | 59.912 | 67.860 | 1.00 | 19.00 | B | N |
| ATOM | 3947 | CA | ASN | B | 591 | 24.877 | 60.918 | 67.306 | 1.00 | 16.88 | B | C |
| ATOM | 3948 | CB | ASN | B | 591 | 25.381 | 62.334 | 67.609 | 1.00 | 16.47 | B | C |
| ATOM | 3949 | CG | ASN | B | 591 | 26.711 | 62.641 | 66.972 | 1.00 | 17.24 | B | C |
| ATOM | 3950 | OD1 | ASN | B | 591 | 27.750 | 62.612 | 67.630 | 1.00 | 18.57 | B | O |
| ATOM | 3951 | ND2 | ASN | B | 591 | 26.689 | 62.960 | 65.692 | 1.00 | 16.80 | B | N |
| ATOM | 3952 | C | ASN | B | 591 | 24.729 | 60.681 | 65.799 | 1.00 | 16.86 | B | C |
| ATOM | 3953 | O | ASN | B | 591 | 25.440 | 59.847 | 65.233 | 1.00 | 15.03 | B | O |
| ATOM | 3954 | N | ILE | B | 592 | 23.803 | 61.390 | 65.154 | 1.00 | 16.60 | B | N |
| ATOM | 3955 | CA | ILE | B | 592 | 23.574 | 61.196 | 63.719 | 1.00 | 15.43 | B | C |
| ATOM | 3956 | CB | ILE | B | 592 | 22.267 | 60.393 | 63.458 | 1.00 | 13.93 | B | C |
| ATOM | 3957 | CG2 | ILE | B | 592 | 22.324 | 59.039 | 64.134 | 1.00 | 11.68 | B | C |
| ATOM | 3958 | CG1 | ILE | B | 592 | 21.063 | 61.182 | 63.977 | 1.00 | 15.55 | B | C |
| ATOM | 3959 | CD1 | ILE | B | 592 | 19.746 | 60.804 | 63.309 | 1.00 | 13.57 | B | C |
| ATOM | 3960 | C | ILE | B | 592 | 23.473 | 62.493 | 62.921 | 1.00 | 15.06 | B | C |
| ATOM | 3961 | O | ILE | B | 592 | 23.534 | 63.592 | 63.478 | 1.00 | 15.04 | B | O |
| ATOM | 3962 | N | SER | B | 593 | 23.326 | 62.333 | 61.606 | 1.00 | 15.07 | B | N |
| ATOM | 3963 | CA | SER | B | 593 | 23.171 | 63.446 | 60.669 | 1.00 | 13.35 | B | C |
| ATOM | 3964 | CB | SER | B | 593 | 24.319 | 63.467 | 59.667 | 1.00 | 13.47 | B | C |
| ATOM | 3965 | OG | SER | B | 593 | 25.498 | 63.947 | 60.269 | 1.00 | 12.52 | B | O |
| ATOM | 3966 | C | SER | B | 593 | 21.856 | 63.252 | 59.923 | 1.00 | 12.31 | B | C |
| ATOM | 3967 | O | SER | B | 593 | 21.526 | 62.132 | 59.525 | 1.00 | 12.84 | B | O |
| ATOM | 3968 | N | HIS | B | 594 | 21.120 | 64.350 | 59.754 | 1.00 | 13.56 | B | N |
| ATOM | 3969 | CA | HIS | B | 594 | 19.814 | 64.409 | 59.073 | 1.00 | 13.96 | B | C |
| ATOM | 3970 | CB | HIS | B | 594 | 19.756 | 63.467 | 57.847 | 1.00 | 13.55 | B | C |
| ATOM | 3971 | CG | HIS | B | 594 | 20.668 | 63.874 | 56.725 | 1.00 | 13.09 | B | C |
| ATOM | 3972 | CD2 | HIS | B | 594 | 21.675 | 63.207 | 56.110 | 1.00 | 11.96 | B | C |
| ATOM | 3973 | ND1 | HIS | B | 594 | 20.642 | 65.132 | 56.157 | 1.00 | 11.93 | B | N |
| ATOM | 3974 | CE1 | HIS | B | 594 | 21.596 | 65.224 | 55.245 | 1.00 | 8.05 | B | C |
| ATOM | 3975 | NE2 | HIS | B | 594 | 22.237 | 64.070 | 55.198 | 1.00 | 11.38 | B | N |
| ATOM | 3976 | C | HIS | B | 594 | 18.663 | 64.110 | 60.033 | 1.00 | 13.29 | B | C |
| ATOM | 3977 | O | HIS | B | 594 | 18.055 | 65.030 | 60.558 | 1.00 | 13.00 | B | O |
| ATOM | 3978 | N | GLY | B | 595 | 18.362 | 62.834 | 60.256 | 1.00 | 13.12 | B | N |
| ATOM | 3979 | CA | GLY | B | 595 | 17.292 | 62.466 | 61.170 | 1.00 | 12.96 | B | C |
| ATOM | 3980 | C | GLY | B | 595 | 15.870 | 62.867 | 60.802 | 1.00 | 14.60 | B | C |
| ATOM | 3981 | O | GLY | B | 595 | 14.972 | 62.813 | 61.643 | 1.00 | 12.75 | B | O |
| ATOM | 3982 | N | LEU | B | 596 | 15.653 | 63.238 | 59.544 | 1.00 | 15.97 | B | N |
| ATOM | 3983 | CA | LEU | B | 596 | 14.337 | 63.670 | 59.063 | 1.00 | 13.96 | B | C |
| ATOM | 3984 | CB | LEU | B | 596 | 14.389 | 63.931 | 57.554 | 1.00 | 13.67 | B | C |
| ATOM | 3985 | CG | LEU | B | 596 | 15.295 | 65.067 | 57.091 | 1.00 | 14.26 | B | C |
| ATOM | 3986 | CD1 | LEU | B | 596 | 15.308 | 65.122 | 55.562 | 1.00 | 13.08 | B | C |
| ATOM | 3987 | CD2 | LEU | B | 596 | 14.793 | 66.383 | 57.684 | 1.00 | 13.07 | B | C |
| ATOM | 3988 | C | LEU | B | 596 | 13.193 | 62.708 | 59.342 | 1.00 | 14.13 | B | C |
| ATOM | 3989 | O | LEU | B | 596 | 12.109 | 63.111 | 59.774 | 1.00 | 13.45 | B | O |
| ATOM | 3990 | N | ASN | B | 597 | 13.431 | 61.433 | 59.086 | 1.00 | 15.09 | B | N |
| ATOM | 3991 | CA | ASN | B | 597 | 12.403 | 60.432 | 59.275 | 1.00 | 15.83 | B | C |
| ATOM | 3992 | CB | ASN | B | 597 | 12.862 | 59.113 | 58.647 | 1.00 | 14.69 | B | C |
| ATOM | 3993 | CG | ASN | B | 597 | 12.571 | 59.061 | 57.166 | 1.00 | 15.47 | B | C |
| ATOM | 3994 | OD1 | ASN | B | 597 | 11.820 | 59.885 | 56.653 | 1.00 | 14.94 | B | O |
| ATOM | 3995 | ND2 | ASN | B | 597 | 13.162 | 58.101 | 56.471 | 1.00 | 14.76 | B | N |
| ATOM | 3996 | C | ASN | B | 597 | 11.908 | 60.213 | 60.706 | 1.00 | 17.16 | B | C |
| ATOM | 3997 | O | ASN | B | 597 | 10.991 | 59.410 | 60.923 | 1.00 | 15.93 | B | O |
| ATOM | 3998 | N | LEU | B | 598 | 12.492 | 60.908 | 61.684 | 1.00 | 16.27 | B | N |
| ATOM | 3999 | CA | LEU | B | 598 | 12.014 | 60.756 | 63.065 | 1.00 | 17.50 | B | C |
| ATOM | 4000 | CB | LEU | B | 598 | 12.892 | 61.543 | 64.047 | 1.00 | 16.38 | B | C |
| ATOM | 4001 | CG | LEU | B | 598 | 14.223 | 60.871 | 64.402 | 1.00 | 16.05 | B | C |
| ATOM | 4002 | CD1 | LEU | B | 598 | 15.088 | 61.825 | 65.208 | 1.00 | 15.41 | B | C |
| ATOM | 4003 | CD2 | LEU | B | 598 | 13.955 | 59.583 | 65.169 | 1.00 | 13.73 | B | C |
| ATOM | 4004 | C | LEU | B | 598 | 10.588 | 61.304 | 63.088 | 1.00 | 18.15 | B | C |
| ATOM | 4005 | O | LEU | B | 598 | 9.774 | 60.952 | 63.944 | 1.00 | 15.96 | B | O |
| ATOM | 4006 | N | LYS | B | 599 | 10.305 | 62.166 | 62.114 | 1.00 | 18.99 | B | N |
| ATOM | 4007 | CA | LYS | B | 599 | 8.998 | 62.784 | 61.955 | 1.00 | 20.59 | B | C |
| ATOM | 4008 | CB | LYS | B | 599 | 9.006 | 63.723 | 60.748 | 1.00 | 24.42 | B | C |
| ATOM | 4009 | CG | LYS | B | 599 | 9.285 | 65.161 | 61.090 | 1.00 | 29.19 | B | C |
| ATOM | 4010 | CD | LYS | B | 599 | 8.001 | 65.978 | 61.119 | 1.00 | 34.96 | B | C |
| ATOM | 4011 | CE | LYS | B | 599 | 7.964 | 66.923 | 62.319 | 1.00 | 35.31 | B | C |
| ATOM | 4012 | NZ | LYS | B | 599 | 7.248 | 66.313 | 63.471 | 1.00 | 37.89 | B | N |
| ATOM | 4013 | C | LYS | B | 599 | 7.913 | 61.744 | 61.746 | 1.00 | 19.21 | B | C |
| ATOM | 4014 | O | LYS | B | 599 | 6.755 | 61.993 | 62.052 | 1.00 | 19.38 | B | O |
| ATOM | 4015 | N | LYS | B | 600 | 8.288 | 60.582 | 61.224 | 1.00 | 17.56 | B | N |
| ATOM | 4016 | CA | LYS | B | 600 | 7.319 | 59.526 | 60.954 | 1.00 | 19.57 | B | C |
| ATOM | 4017 | CB | LYS | B | 600 | 7.673 | 58.812 | 59.649 | 1.00 | 21.22 | B | C |
| ATOM | 4018 | CG | LYS | B | 600 | 7.814 | 59.719 | 58.440 | 1.00 | 24.55 | B | C |
| ATOM | 4019 | CD | LYS | B | 600 | 8.379 | 58.941 | 57.264 | 1.00 | 28.42 | B | C |
| ATOM | 4020 | CE | LYS | B | 600 | 8.199 | 59.703 | 55.960 | 1.00 | 31.12 | B | C |
| ATOM | 4021 | NZ | LYS | B | 600 | 8.821 | 58.985 | 54.804 | 1.00 | 35.09 | B | N |
| ATOM | 4022 | C | LYS | B | 600 | 7.159 | 58.475 | 62.052 | 1.00 | 20.43 | B | C |
| ATOM | 4023 | O | LYS | B | 600 | 6.316 | 57.587 | 61.933 | 1.00 | 21.09 | B | O |
| ATOM | 4024 | N | SER | B | 601 | 7.964 | 58.562 | 63.106 | 1.00 | 19.21 | B | N |
| ATOM | 4025 | CA | SER | B | 601 | 7.892 | 57.595 | 64.207 | 1.00 | 19.18 | B | C |
| ATOM | 4026 | CB | SER | B | 601 | 9.108 | 56.670 | 64.183 | 1.00 | 16.72 | B | C |
| ATOM | 4027 | OG | SER | B | 601 | 8.978 | 55.667 | 65.164 | 1.00 | 20.33 | B | O |
| ATOM | 4028 | C | SER | B | 601 | 7.832 | 58.292 | 65.564 | 1.00 | 18.88 | B | C |
| ATOM | 4029 | O | SER | B | 601 | 8.842 | 58.801 | 66.057 | 1.00 | 17.58 | B | O |
| ATOM | 4030 | N | PRO | B | 602 | 6.645 | 58.315 | 66.187 | 1.00 | 19.08 | B | N |
| ATOM | 4031 | CD | PRO | B | 602 | 5.392 | 57.708 | 65.703 | 1.00 | 19.54 | B | C |
| ATOM | 4032 | CA | PRO | B | 602 | 6.467 | 58.959 | 67.495 | 1.00 | 18.89 | B | C |
| ATOM | 4033 | CB | PRO | B | 602 | 4.965 | 58.833 | 67.759 | 1.00 | 18.36 | B | C |
| ATOM | 4034 | CG | PRO | B | 602 | 4.546 | 57.650 | 66.947 | 1.00 | 19.10 | B | C |
| ATOM | 4035 | C | PRO | B | 602 | 7.299 | 58.256 | 68.562 | 1.00 | 18.37 | B | C |
| ATOM | 4036 | O | PRO | B | 602 | 7.855 | 58.892 | 69.455 | 1.00 | 17.75 | B | O |
| ATOM | 4037 | N | VAL | B | 603 | 7.388 | 56.935 | 68.448 | 1.00 | 19.49 | B | N |
| ATOM | 4038 | CA | VAL | B | 603 | 8.152 | 56.140 | 69.398 | 1.00 | 18.89 | B | C |
| ATOM | 4039 | CB | VAL | B | 603 | 7.882 | 54.626 | 69.195 | 1.00 | 18.33 | B | C |
| ATOM | 4040 | CG1 | VAL | B | 603 | 8.707 | 53.810 | 70.171 | 1.00 | 18.64 | B | C |
| ATOM | 4041 | CG2 | VAL | B | 603 | 6.400 | 54.332 | 69.405 | 1.00 | 15.22 | B | C |
| ATOM | 4042 | C | VAL | B | 603 | 9.652 | 56.434 | 69.280 | 1.00 | 19.62 | B | C |
| ATOM | 4043 | O | VAL | B | 603 | 10.315 | 56.686 | 70.290 | 1.00 | 20.56 | B | O |
| ATOM | 4044 | N | LEU | B | 604 | 10.184 | 56.430 | 68.057 | 1.00 | 17.08 | B | N |
| ATOM | 4045 | CA | LEU | B | 604 | 11.606 | 56.705 | 67.866 | 1.00 | 14.80 | B | C |
| ATOM | 4046 | CB | LEU | B | 604 | 12.051 | 56.282 | 66.456 | 1.00 | 15.33 | B | C |
| ATOM | 4047 | CG | LEU | B | 604 | 12.372 | 54.791 | 66.270 | 1.00 | 14.03 | B | C |
| ATOM | 4048 | CD1 | LEU | B | 604 | 12.442 | 54.452 | 64.791 | 1.00 | 12.86 | B | C |
| ATOM | 4049 | CD2 | LEU | B | 604 | 13.694 | 54.467 | 66.943 | 1.00 | 14.77 | B | C |
| ATOM | 4050 | C | LEU | B | 604 | 11.951 | 58.176 | 68.112 | 1.00 | 13.30 | B | C |
| ATOM | 4051 | O | LEU | B | 604 | 13.029 | 58.496 | 68.613 | 1.00 | 12.57 | B | O |
| ATOM | 4052 | N | GLN | B | 605 | 11.039 | 59.073 | 67.758 | 1.00 | 12.81 | B | N |
| ATOM | 4053 | CA | GLN | B | 605 | 11.260 | 60.498 | 67.966 | 1.00 | 11.36 | B | C |
| ATOM | 4054 | CB | GLN | B | 605 | 10.136 | 61.303 | 67.315 | 1.00 | 9.27 | B | C |
| ATOM | 4055 | CG | GLN | B | 605 | 10.382 | 62.808 | 67.287 | 1.00 | 10.02 | B | C |
| ATOM | 4056 | CD | GLN | B | 605 | 9.185 | 63.559 | 66.741 | 1.00 | 12.86 | B | C |
| ATOM | 4057 | OE1 | GLN | B | 605 | 8.430 | 63.021 | 65.925 | 1.00 | 16.02 | B | O |
| ATOM | 4058 | NE2 | GLN | B | 605 | 8.998 | 64.797 | 67.188 | 1.00 | 7.87 | B | N |
| ATOM | 4059 | C | GLN | B | 605 | 11.323 | 60.820 | 69.464 | 1.00 | 11.00 | B | C |
| ATOM | 4060 | O | GLN | B | 605 | 12.125 | 61.647 | 69.901 | 1.00 | 10.86 | B | O |
| ATOM | 4061 | N | TYR | B | 606 | 10.469 | 60.163 | 70.242 | 1.00 | 11.63 | B | N |
| ATOM | 4062 | CA | TYR | B | 606 | 10.420 | 60.370 | 71.691 | 1.00 | 12.44 | B | C |
| ATOM | 4063 | CB | TYR | B | 606 | 9.145 | 59.739 | 72.264 | 1.00 | 12.27 | B | C |
| ATOM | 4064 | CG | TYR | B | 606 | 8.815 | 60.163 | 73.685 | 1.00 | 12.49 | B | C |
| ATOM | 4065 | CD1 | TYR | B | 606 | 8.697 | 61.514 | 74.023 | 1.00 | 13.53 | B | C |
| ATOM | 4066 | CE1 | TYR | B | 606 | 8.388 | 61.908 | 75.326 | 1.00 | 12.51 | B | C |
| ATOM | 4067 | CD2 | TYR | B | 606 | 8.616 | 59.212 | 74.687 | 1.00 | 9.61 | B | C |
| ATOM | 4068 | CE2 | TYR | B | 606 | 8.307 | 59.594 | 75.991 | 1.00 | 12.64 | B | C |
| ATOM | 4069 | CZ | TYR | B | 606 | 8.195 | 60.939 | 76.301 | 1.00 | 12.08 | B | C |
| ATOM | 4070 | OH | TYR | B | 606 | 7.892 | 61.311 | 77.586 | 1.00 | 15.21 | B | O |
| ATOM | 4071 | C | TYR | B | 606 | 11.662 | 59.770 | 72.353 | 1.00 | 11.87 | B | C |
| ATOM | 4072 | O | TYR | B | 606 | 12.233 | 60.357 | 73.281 | 1.00 | 12.10 | B | O |
| ATOM | 4073 | N | LEU | B | 607 | 12.087 | 58.606 | 71.865 | 1.00 | 11.79 | B | N |
| ATOM | 4074 | CA | LEU | B | 607 | 13.280 | 57.946 | 72.394 | 1.00 | 10.69 | B | C |
| ATOM | 4075 | CB | LEU | B | 607 | 13.467 | 56.583 | 71.733 | 1.00 | 10.88 | B | C |
| ATOM | 4076 | CG | LEU | B | 607 | 12.576 | 55.473 | 72.288 | 1.00 | 13.63 | B | C |
| ATOM | 4077 | CD1 | LEU | B | 607 | 12.887 | 54.180 | 71.566 | 1.00 | 11.80 | B | C |
| ATOM | 4078 | CD2 | LEU | B | 607 | 12.803 | 55.321 | 73.795 | 1.00 | 10.72 | B | C |
| ATOM | 4079 | C | LEU | B | 607 | 14.510 | 58.805 | 72.143 | 1.00 | 11.06 | B | C |
| ATOM | 4080 | O | LEU | B | 607 | 15.420 | 58.856 | 72.966 | 1.00 | 11.22 | B | O |
| ATOM | 4081 | N | PHE | B | 608 | 14.542 | 59.496 | 71.008 | 1.00 | 11.57 | B | N |
| ATOM | 4082 | CA | PHE | B | 608 | 15.682 | 60.344 | 70.708 | 1.00 | 11.01 | B | C |
| ATOM | 4083 | CB | PHE | B | 608 | 15.654 | 60.793 | 69.240 | 1.00 | 9.27 | B | C |
| ATOM | 4084 | CG | PHE | B | 608 | 16.438 | 59.895 | 68.323 | 1.00 | 9.11 | B | C |
| ATOM | 4085 | CD1 | PHE | B | 608 | 16.035 | 58.580 | 68.106 | 1.00 | 9.11 | B | C |
| ATOM | 4086 | CD2 | PHE | B | 608 | 17.582 | 60.359 | 67.682 | 1.00 | 6.81 | B | C |
| ATOM | 4087 | CE1 | PHE | B | 608 | 16.765 | 57.737 | 67.260 | 1.00 | 11.43 | B | C |
| ATOM | 4088 | CE2 | PHE | B | 608 | 18.317 | 59.529 | 66.836 | 1.00 | 7.30 | B | C |
| ATOM | 4089 | CZ | PHE | B | 608 | 17.909 | 58.215 | 66.623 | 1.00 | 9.27 | B | C |
| ATOM | 4090 | C | PHE | B | 608 | 15.676 | 61.549 | 71.643 | 1.00 | 10.36 | B | C |
| ATOM | 4091 | O | PHE | B | 608 | 16.727 | 62.103 | 71.963 | 1.00 | 11.23 | B | O |
| ATOM | 4092 | N | PHE | B | 609 | 14.487 | 61.955 | 72.076 | 1.00 | 12.07 | B | N |
| ATOM | 4093 | CA | PHE | B | 609 | 14.348 | 63.074 | 72.999 | 1.00 | 11.34 | B | C |
| ATOM | 4094 | CB | PHE | B | 609 | 12.896 | 63.547 | 73.051 | 1.00 | 12.50 | B | C |
| ATOM | 4095 | CG | PHE | B | 609 | 12.604 | 64.450 | 74.219 | 1.00 | 13.12 | B | C |
| ATOM | 4096 | CD1 | PHE | B | 609 | 11.962 | 63.954 | 75.359 | 1.00 | 13.38 | B | C |
| ATOM | 4097 | CD2 | PHE | B | 609 | 13.021 | 65.778 | 74.208 | 1.00 | 11.89 | B | C |
| ATOM | 4098 | CE1 | PHE | B | 609 | 11.748 | 64.769 | 76.473 | 1.00 | 10.97 | B | C |
| ATOM | 4099 | CE2 | PHE | B | 609 | 12.810 | 66.603 | 75.317 | 1.00 | 11.32 | B | C |
| ATOM | 4100 | CZ | PHE | B | 609 | 12.173 | 66.095 | 76.452 | 1.00 | 9.86 | B | C |
| ATOM | 4101 | C | PHE | B | 609 | 14.783 | 62.628 | 74.400 | 1.00 | 12.25 | B | C |
| ATOM | 4102 | O | PHE | B | 609 | 15.585 | 63.292 | 75.053 | 1.00 | 13.76 | B | O |
| ATOM | 4103 | N | LEU | B | 610 | 14.244 | 61.500 | 74.854 | 1.00 | 11.78 | B | N |
| ATOM | 4104 | CA | LEU | B | 610 | 14.575 | 60.963 | 76.170 | 1.00 | 12.38 | B | C |
| ATOM | 4105 | CB | LEU | B | 610 | 13.811 | 59.665 | 76.421 | 1.00 | 8.92 | B | C |
| ATOM | 4106 | CG | LEU | B | 610 | 12.295 | 59.772 | 76.518 | 1.00 | 8.30 | B | C |
| ATOM | 4107 | CD1 | LEU | B | 610 | 11.715 | 58.377 | 76.668 | 1.00 | 5.53 | B | C |
| ATOM | 4108 | CD2 | LEU | B | 610 | 11.902 | 60.657 | 77.698 | 1.00 | 9.45 | B | C |
| ATOM | 4109 | C | LEU | B | 610 | 16.075 | 60.706 | 76.328 | 1.00 | 14.65 | B | C |
| ATOM | 4110 | O | LEU | B | 610 | 16.663 | 61.021 | 77.371 | 1.00 | 17.63 | B | O |
| ATOM | 4111 | N | ALA | B | 611 | 16.697 | 60.132 | 75.301 | 1.00 | 14.19 | B | N |
| ATOM | 4112 | CA | ALA | B | 611 | 18.126 | 59.851 | 75.347 | 1.00 | 12.39 | B | C |
| ATOM | 4113 | CB | ALA | B | 611 | 18.454 | 58.663 | 74.454 | 1.00 | 14.25 | B | C |
| ATOM | 4114 | C | ALA | B | 611 | 18.945 | 61.067 | 74.924 | 1.00 | 12.01 | B | C |
| ATOM | 4115 | O | ALA | B | 611 | 20.167 | 61.042 | 74.965 | 1.00 | 12.20 | B | O |
| ATOM | 4116 | N | GLN | B | 612 | 18.261 | 62.136 | 74.531 | 1.00 | 13.11 | B | N |
| ATOM | 4117 | CA | GLN | B | 612 | 18.915 | 63.367 | 74.084 | 1.00 | 14.02 | B | C |
| ATOM | 4118 | CB | GLN | B | 612 | 19.518 | 64.115 | 75.286 | 1.00 | 14.31 | B | C |
| ATOM | 4119 | CG | GLN | B | 612 | 18.525 | 64.988 | 76.059 | 1.00 | 13.18 | B | C |
| ATOM | 4120 | CD | GLN | B | 612 | 17.832 | 66.023 | 75.180 | 1.00 | 18.34 | B | C |
| ATOM | 4121 | OE1 | GLN | B | 612 | 18.409 | 67.061 | 74.850 | 1.00 | 17.27 | B | O |
| ATOM | 4122 | NE2 | GLN | B | 612 | 16.588 | 65.743 | 74.799 | 1.00 | 16.56 | B | N |
| ATOM | 4123 | C | GLN | B | 612 | 20.002 | 63.121 | 73.018 | 1.00 | 13.55 | B | C |
| ATOM | 4124 | O | GLN | B | 612 | 21.086 | 63.703 | 73.078 | 1.00 | 13.43 | B | O |
| ATOM | 4125 | N | ILE | B | 613 | 19.702 | 62.269 | 72.038 | 1.00 | 14.23 | B | N |
| ATOM | 4126 | CA | ILE | B | 613 | 20.656 | 61.955 | 70.973 | 1.00 | 11.58 | B | C |
| ATOM | 4127 | CB | ILE | B | 613 | 20.161 | 60.749 | 70.143 | 1.00 | 10.35 | B | C |
| ATOM | 4128 | CG2 | ILE | B | 613 | 21.226 | 60.340 | 69.120 | 1.00 | 8.86 | B | C |
| ATOM | 4129 | CG1 | ILE | B | 613 | 19.834 | 59.584 | 71.078 | 1.00 | 9.51 | B | C |
| ATOM | 4130 | CD1 | ILE | B | 613 | 19.369 | 58.322 | 70.384 | 1.00 | 8.92 | B | C |
| ATOM | 4131 | C | ILE | B | 613 | 20.869 | 63.161 | 70.044 | 1.00 | 12.09 | B | C |
| ATOM | 4132 | O | ILE | B | 613 | 19.927 | 63.648 | 69.425 | 1.00 | 16.25 | B | O |
| ATOM | 4133 | N | PRO | B | 614 | 22.112 | 63.661 | 69.939 | 1.00 | 10.76 | B | N |
| ATOM | 4134 | CD | PRO | B | 614 | 23.333 | 63.191 | 70.617 | 1.00 | 10.13 | B | C |
| ATOM | 4135 | CA | PRO | B | 614 | 22.376 | 64.813 | 69.063 | 1.00 | 10.07 | B | C |
| ATOM | 4136 | CB | PRO | B | 614 | 23.846 | 65.140 | 69.310 | 1.00 | 9.12 | B | C |
| ATOM | 4137 | CG | PRO | B | 614 | 24.234 | 64.375 | 70.535 | 1.00 | 7.95 | B | C |
| ATOM | 4138 | C | PRO | B | 614 | 22.111 | 64.515 | 67.583 | 1.00 | 10.71 | B | C |
| ATOM | 4139 | O | PRO | B | 614 | 22.466 | 63.447 | 67.079 | 1.00 | 11.07 | B | O |
| ATOM | 4140 | N | ILE | B | 615 | 21.482 | 65.467 | 66.904 | 1.00 | 11.99 | B | N |
| ATOM | 4141 | CA | ILE | B | 615 | 21.151 | 65.337 | 65.483 | 1.00 | 11.33 | B | C |
| ATOM | 4142 | CB | ILE | B | 615 | 19.612 | 65.228 | 65.261 | 1.00 | 11.64 | B | C |
| ATOM | 4143 | CG2 | ILE | B | 615 | 19.296 | 65.132 | 63.765 | 1.00 | 12.25 | B | C |
| ATOM | 4144 | CG1 | ILE | B | 615 | 19.057 | 63.996 | 65.978 | 1.00 | 9.43 | B | C |
| ATOM | 4145 | CD1 | ILE | B | 615 | 17.595 | 64.121 | 66.346 | 1.00 | 8.98 | B | C |
| ATOM | 4146 | C | ILE | B | 615 | 21.656 | 66.554 | 64.711 | 1.00 | 11.38 | B | C |
| ATOM | 4147 | O | ILE | B | 615 | 21.232 | 67.681 | 64.960 | 1.00 | 11.95 | B | O |
| ATOM | 4148 | N | ALA | B | 616 | 22.586 | 66.331 | 63.790 | 1.00 | 11.93 | B | N |
| ATOM | 4149 | CA | ALA | B | 616 | 23.107 | 67.421 | 62.965 | 1.00 | 11.48 | B | C |
| ATOM | 4150 | CB | ALA | B | 616 | 24.531 | 67.111 | 62.507 | 1.00 | 11.90 | B | C |
| ATOM | 4151 | C | ALA | B | 616 | 22.175 | 67.517 | 61.756 | 1.00 | 12.40 | B | C |
| ATOM | 4152 | O | ALA | B | 616 | 22.084 | 66.576 | 60.960 | 1.00 | 11.70 | B | O |
| ATOM | 4153 | N | MET | B | 617 | 21.467 | 68.636 | 61.636 | 1.00 | 12.58 | B | N |
| ATOM | 4154 | CA | MET | B | 617 | 20.537 | 68.837 | 60.523 | 1.00 | 11.79 | B | C |
| ATOM | 4155 | CB | MET | B | 617 | 19.177 | 69.316 | 61.053 | 1.00 | 13.18 | B | C |
| ATOM | 4156 | CG | MET | B | 617 | 18.609 | 68.488 | 62.216 | 1.00 | 15.39 | B | C |
| ATOM | 4157 | SD | MET | B | 617 | 16.785 | 68.495 | 62.318 | 1.00 | 18.79 | B | S |
| ATOM | 4158 | CE | MET | B | 617 | 16.530 | 69.728 | 63.439 | 1.00 | 24.12 | B | C |
| ATOM | 4159 | C | MET | B | 617 | 21.076 | 69.833 | 59.481 | 1.00 | 12.37 | B | C |
| ATOM | 4160 | O | MET | B | 617 | 21.867 | 70.734 | 59.802 | 1.00 | 11.29 | B | O |
| ATOM | 4161 | N | SER | B | 618 | 20.645 | 69.656 | 58.232 | 1.00 | 14.59 | B | N |
| ATOM | 4162 | CA | SER | B | 618 | 21.056 | 70.502 | 57.105 | 1.00 | 12.73 | B | C |
| ATOM | 4163 | CB | SER | B | 618 | 22.087 | 69.771 | 56.244 | 1.00 | 12.54 | B | C |
| ATOM | 4164 | OG | SER | B | 618 | 23.077 | 69.143 | 57.034 | 1.00 | 14.34 | B | O |
| ATOM | 4165 | C | SER | B | 618 | 19.848 | 70.826 | 56.241 | 1.00 | 12.76 | B | C |
| ATOM | 4166 | O | SER | B | 618 | 19.618 | 70.180 | 55.225 | 1.00 | 14.20 | B | O |
| ATOM | 4167 | N | PRO | B | 619 | 19.046 | 71.821 | 56.645 | 1.00 | 13.40 | B | N |
| ATOM | 4168 | CD | PRO | B | 619 | 19.195 | 72.617 | 57.874 | 1.00 | 9.26 | B | C |
| ATOM | 4169 | CA | PRO | B | 619 | 17.850 | 72.213 | 55.884 | 1.00 | 13.90 | B | C |
| ATOM | 4170 | CB | PRO | B | 619 | 17.229 | 73.327 | 56.738 | 1.00 | 15.42 | B | C |
| ATOM | 4171 | CG | PRO | B | 619 | 17.807 | 73.121 | 58.112 | 1.00 | 12.68 | B | C |
| ATOM | 4172 | C | PRO | B | 619 | 18.084 | 72.654 | 54.429 | 1.00 | 15.22 | B | C |
| ATOM | 4173 | O | PRO | B | 619 | 17.272 | 72.344 | 53.557 | 1.00 | 16.05 | B | O |
| ATOM | 4174 | N | LEU | B | 620 | 19.169 | 73.380 | 54.164 | 1.00 | 14.25 | B | N |
| ATOM | 4175 | CA | LEU | B | 620 | 19.441 | 73.818 | 52.801 | 1.00 | 15.45 | B | C |
| ATOM | 4176 | CB | LEU | B | 620 | 20.609 | 74.804 | 52.774 | 1.00 | 13.60 | B | C |
| ATOM | 4177 | CG | LEU | B | 620 | 20.240 | 76.231 | 53.202 | 1.00 | 13.47 | B | C |
| ATOM | 4178 | CD1 | LEU | B | 620 | 21.476 | 77.119 | 53.178 | 1.00 | 11.42 | B | C |
| ATOM | 4179 | CD2 | LEU | B | 620 | 19.171 | 76.793 | 52.279 | 1.00 | 14.35 | B | C |
| ATOM | 4180 | C | LEU | B | 620 | 19.735 | 72.611 | 51.907 | 1.00 | 16.20 | B | C |
| ATOM | 4181 | O | LEU | B | 620 | 19.261 | 72.533 | 50.772 | 1.00 | 17.04 | B | O |
| ATOM | 4182 | N | SER | B | 621 | 20.505 | 71.661 | 52.426 | 1.00 | 15.84 | B | N |
| ATOM | 4183 | CA | SER | B | 621 | 20.827 | 70.456 | 51.677 | 1.00 | 15.64 | B | C |
| ATOM | 4184 | CB | SER | B | 621 | 21.885 | 69.642 | 52.421 | 1.00 | 15.78 | B | C |
| ATOM | 4185 | OG | SER | B | 621 | 21.886 | 68.294 | 51.988 | 1.00 | 16.62 | B | O |
| ATOM | 4186 | C | SER | B | 621 | 19.564 | 69.610 | 51.449 | 1.00 | 17.29 | B | C |
| ATOM | 4187 | O | SER | B | 621 | 19.337 | 69.104 | 50.343 | 1.00 | 17.79 | B | O |
| ATOM | 4188 | N | ASN | B | 622 | 18.742 | 69.458 | 52.488 | 1.00 | 16.43 | B | N |
| ATOM | 4189 | CA | ASN | B | 622 | 17.502 | 68.687 | 52.377 | 1.00 | 15.66 | B | C |
| ATOM | 4190 | CB | ASN | B | 622 | 16.752 | 68.658 | 53.713 | 1.00 | 15.80 | B | C |
| ATOM | 4191 | CG | ASN | B | 622 | 17.559 | 68.039 | 54.837 | 1.00 | 17.76 | B | C |
| ATOM | 4192 | OD1 | ASN | B | 622 | 17.223 | 68.208 | 56.006 | 1.00 | 17.27 | B | O |
| ATOM | 4193 | ND2 | ASN | B | 622 | 18.617 | 67.316 | 54.493 | 1.00 | 17.33 | B | N |
| ATOM | 4194 | C | ASN | B | 622 | 16.576 | 69.315 | 51.333 | 1.00 | 15.97 | B | C |
| ATOM | 4195 | O | ASN | B | 622 | 15.909 | 68.611 | 50.576 | 1.00 | 15.00 | B | O |
| ATOM | 4196 | N | ASN | B | 623 | 16.528 | 70.644 | 51.322 | 1.00 | 16.32 | B | N |
| ATOM | 4197 | CA | ASN | B | 623 | 15.685 | 71.391 | 50.397 | 1.00 | 19.47 | B | C |
| ATOM | 4198 | CB | ASN | B | 623 | 15.813 | 72.884 | 50.695 | 1.00 | 17.85 | B | C |
| ATOM | 4199 | CG | ASN | B | 623 | 15.104 | 73.756 | 49.677 | 1.00 | 15.83 | B | C |
| ATOM | 4200 | OD1 | ASN | B | 623 | 15.736 | 74.556 | 48.982 | 1.00 | 16.79 | B | O |
| ATOM | 4201 | ND2 | ASN | B | 623 | 13.791 | 73.622 | 49.593 | 1.00 | 13.39 | B | N |
| ATOM | 4202 | C | ASN | B | 623 | 16.050 | 71.113 | 48.942 | 1.00 | 23.11 | B | C |
| ATOM | 4203 | O | ASN | B | 623 | 15.198 | 71.128 | 48.063 | 1.00 | 23.81 | B | O |
| ATOM | 4204 | N | SER | B | 624 | 17.323 | 70.842 | 48.701 | 1.00 | 26.94 | B | N |
| ATOM | 4205 | CA | SER | B | 624 | 17.815 | 70.573 | 47.358 | 1.00 | 31.87 | B | C |
| ATOM | 4206 | CB | SER | B | 624 | 19.223 | 71.152 | 47.204 | 1.00 | 33.23 | B | C |
| ATOM | 4207 | OG | SER | B | 624 | 19.384 | 71.804 | 45.961 | 1.00 | 40.30 | B | O |
| ATOM | 4208 | C | SER | B | 624 | 17.866 | 69.092 | 47.018 | 1.00 | 33.23 | B | C |
| ATOM | 4209 | O | SER | B | 624 | 18.104 | 68.734 | 45.869 | 1.00 | 33.48 | B | O |
| ATOM | 4210 | N | LEU | B | 625 | 17.635 | 68.232 | 48.006 | 1.00 | 35.59 | B | N |
| ATOM | 4211 | CA | LEU | B | 625 | 17.723 | 66.797 | 47.776 | 1.00 | 36.84 | B | C |
| ATOM | 4212 | CB | LEU | B | 625 | 18.920 | 66.237 | 48.558 | 1.00 | 38.63 | B | C |
| ATOM | 4213 | CG | LEU | B | 625 | 20.171 | 65.678 | 47.865 | 1.00 | 40.69 | B | C |
| ATOM | 4214 | CD1 | LEU | B | 625 | 19.976 | 65.583 | 46.373 | 1.00 | 43.30 | B | C |
| ATOM | 4215 | CD2 | LEU | B | 625 | 21.346 | 66.566 | 48.178 | 1.00 | 41.95 | B | C |
| ATOM | 4216 | C | LEU | B | 625 | 16.493 | 65.938 | 48.079 | 1.00 | 35.96 | B | C |
| ATOM | 4217 | O | LEU | B | 625 | 16.123 | 65.089 | 47.267 | 1.00 | 36.79 | B | O |
| ATOM | 4218 | N | PHE | B | 626 | 15.859 | 66.141 | 49.231 | 1.00 | 35.65 | B | N |
| ATOM | 4219 | CA | PHE | B | 626 | 14.713 | 65.307 | 49.598 | 1.00 | 33.72 | B | C |
| ATOM | 4220 | CB | PHE | B | 626 | 15.163 | 64.217 | 50.584 | 1.00 | 33.23 | B | C |
| ATOM | 4221 | CG | PHE | B | 626 | 16.139 | 63.227 | 50.006 | 1.00 | 34.79 | B | C |
| ATOM | 4222 | CD1 | PHE | B | 626 | 15.690 | 62.112 | 49.305 | 1.00 | 34.54 | B | C |
| ATOM | 4223 | CD2 | PHE | B | 626 | 17.512 | 63.398 | 50.179 | 1.00 | 35.61 | B | C |
| ATOM | 4224 | CE1 | PHE | B | 626 | 16.595 | 61.183 | 48.786 | 1.00 | 36.01 | B | C |
| ATOM | 4225 | CE2 | PHE | B | 626 | 18.426 | 62.473 | 49.663 | 1.00 | 36.05 | B | C |
| ATOM | 4226 | CZ | PHE | B | 626 | 17.967 | 61.365 | 48.967 | 1.00 | 35.28 | B | C |
| ATOM | 4227 | C | PHE | B | 626 | 13.484 | 65.996 | 50.192 | 1.00 | 32.50 | B | C |
| ATOM | 4228 | O | PHE | B | 626 | 12.390 | 65.450 | 50.119 | 1.00 | 33.34 | B | O |
| ATOM | 4229 | N | LEU | B | 627 | 13.645 | 67.179 | 50.774 | 1.00 | 31.09 | B | N |
| ATOM | 4230 | CA | LEU | B | 627 | 12.513 | 67.854 | 51.407 | 1.00 | 29.64 | B | C |
| ATOM | 4231 | CB | LEU | B | 627 | 12.491 | 67.505 | 52.899 | 1.00 | 30.44 | B | C |
| ATOM | 4232 | CG | LEU | B | 627 | 11.222 | 67.073 | 53.637 | 1.00 | 29.72 | B | C |
| ATOM | 4233 | CD1 | LEU | B | 627 | 11.382 | 67.449 | 55.102 | 1.00 | 27.81 | B | C |
| ATOM | 4234 | CD2 | LEU | B | 627 | 9.985 | 67.719 | 53.051 | 1.00 | 28.50 | B | C |
| ATOM | 4235 | C | LEU | B | 627 | 12.549 | 69.366 | 51.266 | 1.00 | 29.25 | B | C |
| ATOM | 4236 | O | LEU | B | 627 | 13.545 | 69.994 | 51.601 | 1.00 | 30.93 | B | O |
| ATOM | 4237 | N | GLU | B | 628 | 11.447 | 69.946 | 50.803 | 1.00 | 29.35 | B | N |
| ATOM | 4238 | CA | GLU | B | 628 | 11.338 | 71.396 | 50.629 | 1.00 | 30.42 | B | C |
| ATOM | 4239 | CB | GLU | B | 628 | 9.954 | 71.734 | 50.068 | 1.00 | 34.66 | B | C |
| ATOM | 4240 | CG | GLU | B | 628 | 9.425 | 73.118 | 50.409 | 1.00 | 42.11 | B | C |
| ATOM | 4241 | CD | GLU | B | 628 | 7.931 | 73.240 | 50.139 | 1.00 | 46.89 | B | C |
| ATOM | 4242 | OE1 | GLU | B | 628 | 7.376 | 72.350 | 49.455 | 1.00 | 48.12 | B | O |
| ATOM | 4243 | OE2 | GLU | B | 628 | 7.312 | 74.223 | 50.608 | 1.00 | 49.53 | B | O |
| ATOM | 4244 | C | GLU | B | 628 | 11.578 | 72.132 | 51.954 | 1.00 | 27.73 | B | C |
| ATOM | 4245 | O | GLU | B | 628 | 11.069 | 71.718 | 52.996 | 1.00 | 26.59 | B | O |
| ATOM | 4246 | N | TYR | B | 629 | 12.332 | 73.231 | 51.902 | 1.00 | 23.85 | B | N |
| ATOM | 4247 | CA | TYR | B | 629 | 12.670 | 73.997 | 53.097 | 1.00 | 21.92 | B | C |
| ATOM | 4248 | CB | TYR | B | 629 | 13.258 | 75.363 | 52.729 | 1.00 | 20.31 | B | C |
| ATOM | 4249 | CG | TYR | B | 629 | 14.193 | 75.880 | 53.801 | 1.00 | 19.69 | B | C |
| ATOM | 4250 | CD1 | TYR | B | 629 | 13.699 | 76.536 | 54.934 | 1.00 | 19.87 | B | C |
| ATOM | 4251 | CE1 | TYR | B | 629 | 14.549 | 76.926 | 55.975 | 1.00 | 20.86 | B | C |
| ATOM | 4252 | CD2 | TYR | B | 629 | 15.560 | 75.637 | 53.729 | 1.00 | 18.76 | B | C |
| ATOM | 4253 | CE2 | TYR | B | 629 | 16.416 | 76.023 | 54.756 | 1.00 | 21.01 | B | C |
| ATOM | 4254 | CZ | TYR | B | 629 | 15.908 | 76.663 | 55.879 | 1.00 | 22.80 | B | C |
| ATOM | 4255 | OH | TYR | B | 629 | 16.761 | 77.004 | 56.910 | 1.00 | 25.09 | B | O |
| ATOM | 4256 | C | TYR | B | 629 | 11.566 | 74.198 | 54.123 | 1.00 | 21.53 | B | C |
| ATOM | 4257 | O | TYR | B | 629 | 11.685 | 73.746 | 55.259 | 1.00 | 22.27 | B | O |
| ATOM | 4258 | N | ALA | B | 630 | 10.495 | 74.874 | 53.730 | 1.00 | 21.97 | B | N |
| ATOM | 4259 | CA | ALA | B | 630 | 9.387 | 75.148 | 54.640 | 1.00 | 24.13 | B | C |
| ATOM | 4260 | CB | ALA | B | 630 | 8.296 | 75.931 | 53.910 | 1.00 | 23.44 | B | C |
| ATOM | 4261 | C | ALA | B | 630 | 8.786 | 73.903 | 55.298 | 1.00 | 24.26 | B | C |
| ATOM | 4262 | O | ALA | B | 630 | 8.108 | 74.007 | 56.320 | 1.00 | 26.22 | B | O |
| ATOM | 4263 | N | LYS | B | 631 | 9.043 | 72.734 | 54.722 | 1.00 | 23.25 | B | N |
| ATOM | 4264 | CA | LYS | B | 631 | 8.512 | 71.484 | 55.257 | 1.00 | 22.39 | B | C |
| ATOM | 4265 | CB | LYS | B | 631 | 8.201 | 70.520 | 54.108 | 1.00 | 26.01 | B | C |
| ATOM | 4266 | CG | LYS | B | 631 | 6.764 | 70.558 | 53.608 | 1.00 | 30.97 | B | C |
| ATOM | 4267 | CD | LYS | B | 631 | 6.354 | 71.964 | 53.187 | 1.00 | 37.57 | B | C |
| ATOM | 4268 | CE | LYS | B | 631 | 4.865 | 72.215 | 53.438 | 1.00 | 40.95 | B | C |
| ATOM | 4269 | NZ | LYS | B | 631 | 4.389 | 73.482 | 52.795 | 1.00 | 43.21 | B | N |
| ATOM | 4270 | C | LYS | B | 631 | 9.476 | 70.799 | 56.231 | 1.00 | 20.67 | B | C |
| ATOM | 4271 | O | LYS | B | 631 | 9.158 | 69.749 | 56.790 | 1.00 | 20.06 | B | O |
| ATOM | 4272 | N | ASN | B | 632 | 10.647 | 71.393 | 56.437 | 1.00 | 18.03 | B | N |
| ATOM | 4273 | CA | ASN | B | 632 | 11.651 | 70.808 | 57.324 | 1.00 | 17.74 | B | C |
| ATOM | 4274 | CB | ASN | B | 632 | 12.968 | 71.572 | 57.200 | 1.00 | 15.35 | B | C |
| ATOM | 4275 | CG | ASN | B | 632 | 14.154 | 70.729 | 57.575 | 1.00 | 16.99 | B | C |
| ATOM | 4276 | OD1 | ASN | B | 632 | 14.904 | 70.279 | 56.709 | 1.00 | 17.78 | B | O |
| ATOM | 4277 | ND2 | ASN | B | 632 | 14.335 | 70.500 | 58.875 | 1.00 | 15.08 | B | N |
| ATOM | 4278 | C | ASN | B | 632 | 11.247 | 70.742 | 58.800 | 1.00 | 17.33 | B | C |
| ATOM | 4279 | O | ASN | B | 632 | 10.815 | 71.738 | 59.379 | 1.00 | 16.93 | B | O |
| ATOM | 4280 | N | PRO | B | 633 | 11.400 | 69.561 | 59.430 | 1.00 | 16.68 | B | N |
| ATOM | 4281 | CD | PRO | B | 633 | 11.907 | 68.304 | 58.847 | 1.00 | 15.87 | B | C |
| ATOM | 4282 | CA | PRO | B | 633 | 11.044 | 69.396 | 60.845 | 1.00 | 16.46 | B | C |
| ATOM | 4283 | CB | PRO | B | 633 | 10.985 | 67.887 | 61.024 | 1.00 | 15.00 | B | C |
| ATOM | 4284 | CG | PRO | B | 633 | 11.969 | 67.369 | 60.030 | 1.00 | 14.78 | B | C |
| ATOM | 4285 | C | PRO | B | 633 | 12.039 | 70.030 | 61.816 | 1.00 | 16.40 | B | C |
| ATOM | 4286 | O | PRO | B | 633 | 11.968 | 69.771 | 63.008 | 1.00 | 18.83 | B | O |
| ATOM | 4287 | N | PHE | B | 634 | 12.955 | 70.856 | 61.310 | 1.00 | 14.58 | B | N |
| ATOM | 4288 | CA | PHE | B | 634 | 13.952 | 71.499 | 62.154 | 1.00 | 14.03 | B | C |
| ATOM | 4289 | CB | PHE | B | 634 | 14.830 | 72.443 | 61.320 | 1.00 | 13.29 | B | C |
| ATOM | 4290 | CG | PHE | B | 634 | 15.731 | 73.325 | 62.152 | 1.00 | 16.70 | B | C |
| ATOM | 4291 | CD1 | PHE | B | 634 | 15.388 | 74.650 | 62.409 | 1.00 | 18.30 | B | C |
| ATOM | 4292 | CD2 | PHE | B | 634 | 16.894 | 72.817 | 62.725 | 1.00 | 15.77 | B | C |
| ATOM | 4293 | CE1 | PHE | B | 634 | 16.186 | 75.449 | 63.225 | 1.00 | 16.75 | B | C |
| ATOM | 4294 | CE2 | PHE | B | 634 | 17.697 | 73.611 | 63.543 | 1.00 | 16.49 | B | C |
| ATOM | 4295 | CZ | PHE | B | 634 | 17.340 | 74.927 | 63.793 | 1.00 | 14.68 | B | C |
| ATOM | 4296 | C | PHE | B | 634 | 13.360 | 72.270 | 63.343 | 1.00 | 14.94 | B | C |
| ATOM | 4297 | O | PHE | B | 634 | 13.747 | 72.042 | 64.491 | 1.00 | 14.15 | B | O |
| ATOM | 4298 | N | LEU | B | 635 | 12.434 | 73.182 | 63.070 | 1.00 | 12.63 | B | N |
| ATOM | 4299 | CA | LEU | B | 635 | 11.832 | 73.983 | 64.127 | 1.00 | 13.27 | B | C |
| ATOM | 4300 | CB | LEU | B | 635 | 10.922 | 75.059 | 63.520 | 1.00 | 12.22 | B | C |
| ATOM | 4301 | CG | LEU | B | 635 | 10.166 | 75.965 | 64.494 | 1.00 | 9.59 | B | C |
| ATOM | 4302 | CD1 | LEU | B | 635 | 11.163 | 76.744 | 65.331 | 1.00 | 8.88 | B | C |
| ATOM | 4303 | CD2 | LEU | B | 635 | 9.254 | 76.909 | 63.726 | 1.00 | 8.81 | B | C |
| ATOM | 4304 | C | LEU | B | 635 | 11.036 | 73.135 | 65.119 | 1.00 | 15.11 | B | C |
| ATOM | 4305 | O | LEU | B | 635 | 11.126 | 73.341 | 66.323 | 1.00 | 16.54 | B | O |
| ATOM | 4306 | N | ASP | B | 636 | 10.254 | 72.189 | 64.606 | 1.00 | 13.50 | B | N |
| ATOM | 4307 | CA | ASP | B | 636 | 9.455 | 71.308 | 65.443 | 1.00 | 13.56 | B | C |
| ATOM | 4308 | CB | ASP | B | 636 | 8.699 | 70.313 | 64.572 | 1.00 | 14.22 | B | C |
| ATOM | 4309 | CG | ASP | B | 636 | 7.631 | 69.566 | 65.339 | 1.00 | 16.55 | B | C |
| ATOM | 4310 | OD1 | ASP | B | 636 | 6.797 | 70.229 | 65.992 | 1.00 | 18.19 | B | O |
| ATOM | 4311 | OD2 | ASP | B | 636 | 7.620 | 68.321 | 65.289 | 1.00 | 16.75 | B | O |
| ATOM | 4312 | C | ASP | B | 636 | 10.326 | 70.540 | 66.440 | 1.00 | 15.06 | B | C |
| ATOM | 4313 | O | ASP | B | 636 | 10.006 | 70.454 | 67.630 | 1.00 | 15.75 | B | O |
| ATOM | 4314 | N | PHE | B | 637 | 11.417 | 69.968 | 65.941 | 1.00 | 13.59 | B | N |
| ATOM | 4315 | CA | PHE | B | 637 | 12.343 | 69.214 | 66.768 | 1.00 | 13.57 | B | C |
| ATOM | 4316 | CB | PHE | B | 637 | 13.430 | 68.567 | 65.894 | 1.00 | 11.16 | B | C |
| ATOM | 4317 | CG | PHE | B | 637 | 12.950 | 67.401 | 65.067 | 1.00 | 10.78 | B | C |
| ATOM | 4318 | CD1 | PHE | B | 637 | 11.622 | 66.996 | 65.096 | 1.00 | 10.53 | B | C |
| ATOM | 4319 | CD2 | PHE | B | 637 | 13.845 | 66.694 | 64.259 | 1.00 | 13.21 | B | C |
| ATOM | 4320 | CE1 | PHE | B | 637 | 11.188 | 65.899 | 64.333 | 1.00 | 12.12 | B | C |
| ATOM | 4321 | CE2 | PHE | B | 637 | 13.421 | 65.595 | 63.494 | 1.00 | 11.56 | B | C |
| ATOM | 4322 | CZ | PHE | B | 637 | 12.094 | 65.199 | 63.532 | 1.00 | 10.49 | B | C |
| ATOM | 4323 | C | PHE | B | 637 | 13.000 | 70.152 | 67.788 | 1.00 | 14.63 | B | C |
| ATOM | 4324 | O | PHE | B | 637 | 13.189 | 69.788 | 68.947 | 1.00 | 15.19 | B | O |
| ATOM | 4325 | N | LEU | B | 638 | 13.341 | 71.359 | 67.348 | 1.00 | 13.62 | B | N |
| ATOM | 4326 | CA | LEU | B | 638 | 13.984 | 72.335 | 68.215 | 1.00 | 14.74 | B | C |
| ATOM | 4327 | CB | LEU | B | 638 | 14.417 | 73.559 | 67.406 | 1.00 | 15.49 | B | C |
| ATOM | 4328 | CG | LEU | B | 638 | 15.016 | 74.686 | 68.249 | 1.00 | 17.56 | B | C |
| ATOM | 4329 | CD1 | LEU | B | 638 | 16.368 | 74.250 | 68.777 | 1.00 | 17.28 | B | C |
| ATOM | 4330 | CD2 | LEU | B | 638 | 15.151 | 75.944 | 67.422 | 1.00 | 17.44 | B | C |
| ATOM | 4331 | C | LEU | B | 638 | 13.070 | 72.783 | 69.346 | 1.00 | 15.30 | B | C |
| ATOM | 4332 | O | LEU | B | 638 | 13.491 | 72.876 | 70.497 | 1.00 | 16.30 | B | O |
| ATOM | 4333 | N | GLN | B | 639 | 11.820 | 73.078 | 69.011 | 1.00 | 14.95 | B | N |
| ATOM | 4334 | CA | GLN | B | 639 | 10.853 | 73.515 | 70.006 | 1.00 | 15.18 | B | C |
| ATOM | 4335 | CB | GLN | B | 639 | 9.558 | 73.941 | 69.322 | 1.00 | 12.41 | B | C |
| ATOM | 4336 | CG | GLN | B | 639 | 9.678 | 75.272 | 68.597 | 1.00 | 13.11 | B | C |
| ATOM | 4337 | CD | GLN | B | 639 | 8.399 | 75.666 | 67.891 | 1.00 | 15.63 | B | C |
| ATOM | 4338 | OE1 | GLN | B | 639 | 7.570 | 74.816 | 67.563 | 1.00 | 16.28 | B | O |
| ATOM | 4339 | NE2 | GLN | B | 639 | 8.231 | 76.959 | 67.654 | 1.00 | 16.83 | B | N |
| ATOM | 4340 | C | GLN | B | 639 | 10.568 | 72.413 | 71.025 | 1.00 | 15.81 | B | C |
| ATOM | 4341 | O | GLN | B | 639 | 10.530 | 72.666 | 72.225 | 1.00 | 16.33 | B | O |
| ATOM | 4342 | N | LYS | B | 640 | 10.381 | 71.191 | 70.538 | 1.00 | 14.87 | B | N |
| ATOM | 4343 | CA | LYS | B | 640 | 10.097 | 70.053 | 71.402 | 1.00 | 14.69 | B | C |
| ATOM | 4344 | CB | LYS | B | 640 | 9.755 | 68.829 | 70.552 | 1.00 | 14.02 | B | C |
| ATOM | 4345 | CG | LYS | B | 640 | 8.356 | 68.845 | 69.955 | 1.00 | 13.67 | B | C |
| ATOM | 4346 | CD | LYS | B | 640 | 8.260 | 67.784 | 68.885 | 1.00 | 11.45 | B | C |
| ATOM | 4347 | CE | LYS | B | 640 | 6.873 | 67.663 | 68.307 | 1.00 | 8.70 | B | C |
| ATOM | 4348 | NZ | LYS | B | 640 | 6.909 | 66.644 | 67.214 | 1.00 | 8.39 | B | N |
| ATOM | 4349 | C | LYS | B | 640 | 11.243 | 69.699 | 72.362 | 1.00 | 14.01 | B | C |
| ATOM | 4350 | O | LYS | B | 640 | 11.024 | 69.014 | 73.358 | 1.00 | 13.63 | B | O |
| ATOM | 4351 | N | GLY | B | 641 | 12.460 | 70.143 | 72.055 | 1.00 | 13.36 | B | N |
| ATOM | 4352 | CA | GLY | B | 641 | 13.583 | 69.853 | 72.925 | 1.00 | 11.11 | B | C |
| ATOM | 4353 | C | GLY | B | 641 | 14.591 | 68.807 | 72.459 | 1.00 | 12.90 | B | C |
| ATOM | 4354 | O | GLY | B | 641 | 15.479 | 68.444 | 73.222 | 1.00 | 12.20 | B | O |
| ATOM | 4355 | N | LEU | B | 642 | 14.472 | 68.297 | 71.233 | 1.00 | 12.83 | B | N |
| ATOM | 4356 | CA | LEU | B | 642 | 15.441 | 67.310 | 70.761 | 1.00 | 11.59 | B | C |
| ATOM | 4357 | CB | LEU | B | 642 | 15.037 | 66.731 | 69.403 | 1.00 | 12.27 | B | C |
| ATOM | 4358 | CG | LEU | B | 642 | 13.691 | 66.008 | 69.167 | 1.00 | 16.75 | B | C |
| ATOM | 4359 | CD1 | LEU | B | 642 | 13.965 | 64.610 | 68.645 | 1.00 | 14.36 | B | C |
| ATOM | 4360 | CD2 | LEU | B | 642 | 12.841 | 65.951 | 70.413 | 1.00 | 16.51 | B | C |
| ATOM | 4361 | C | LEU | B | 642 | 16.797 | 68.005 | 70.641 | 1.00 | 12.35 | B | C |
| ATOM | 4362 | O | LEU | B | 642 | 16.868 | 69.210 | 70.401 | 1.00 | 12.37 | B | O |
| ATOM | 4363 | N | MET | B | 643 | 17.872 | 67.247 | 70.820 | 1.00 | 12.90 | B | N |
| ATOM | 4364 | CA | MET | B | 643 | 19.229 | 67.782 | 70.750 | 1.00 | 14.91 | B | C |
| ATOM | 4365 | CB | MET | B | 643 | 20.199 | 66.765 | 71.370 | 1.00 | 18.70 | B | C |
| ATOM | 4366 | CG | MET | B | 643 | 21.262 | 67.370 | 72.264 | 1.00 | 20.79 | B | C |
| ATOM | 4367 | SD | MET | B | 643 | 22.655 | 67.973 | 71.300 | 1.00 | 29.86 | B | S |
| ATOM | 4368 | CE | MET | B | 643 | 23.951 | 67.983 | 72.558 | 1.00 | 25.70 | B | C |
| ATOM | 4369 | C | MET | B | 643 | 19.625 | 68.097 | 69.298 | 1.00 | 14.94 | B | C |
| ATOM | 4370 | O | MET | B | 643 | 20.262 | 67.280 | 68.623 | 1.00 | 12.78 | B | O |
| ATOM | 4371 | N | ILE | B | 644 | 19.288 | 69.305 | 68.854 | 1.00 | 15.10 | B | N |
| ATOM | 4372 | CA | ILE | B | 644 | 19.526 | 69.735 | 67.472 | 1.00 | 16.74 | B | C |
| ATOM | 4373 | CB | ILE | B | 644 | 18.224 | 70.363 | 66.896 | 1.00 | 17.74 | B | C |
| ATOM | 4374 | CG2 | ILE | B | 644 | 18.457 | 70.849 | 65.493 | 1.00 | 18.06 | B | C |
| ATOM | 4375 | CG1 | ILE | B | 644 | 17.071 | 69.360 | 66.957 | 1.00 | 16.61 | B | C |
| ATOM | 4376 | CD1 | ILE | B | 644 | 17.321 | 68.092 | 66.214 | 1.00 | 18.04 | B | C |
| ATOM | 4377 | C | ILE | B | 644 | 20.665 | 70.732 | 67.183 | 1.00 | 17.26 | B | C |
| ATOM | 4378 | O | ILE | B | 644 | 20.869 | 71.695 | 67.925 | 1.00 | 16.97 | B | O |
| ATOM | 4379 | N | SER | B | 645 | 21.400 | 70.499 | 66.095 | 1.00 | 14.70 | B | N |
| ATOM | 4380 | CA | SER | B | 645 | 22.447 | 71.431 | 65.670 | 1.00 | 13.77 | B | C |
| ATOM | 4381 | CB | SER | B | 645 | 23.854 | 70.910 | 66.019 | 1.00 | 12.97 | B | C |
| ATOM | 4382 | OG | SER | B | 645 | 24.295 | 69.873 | 65.157 | 1.00 | 13.59 | B | O |
| ATOM | 4383 | C | SER | B | 645 | 22.296 | 71.644 | 64.153 | 1.00 | 13.71 | B | C |
| ATOM | 4384 | O | SER | B | 645 | 21.724 | 70.801 | 63.457 | 1.00 | 12.39 | B | O |
| ATOM | 4385 | N | LEU | B | 646 | 22.785 | 72.774 | 63.646 | 1.00 | 13.66 | B | N |
| ATOM | 4386 | CA | LEU | B | 646 | 22.688 | 73.076 | 62.221 | 1.00 | 13.46 | B | C |
| ATOM | 4387 | CB | LEU | B | 646 | 22.318 | 74.548 | 62.009 | 1.00 | 11.63 | B | C |
| ATOM | 4388 | CG | LEU | B | 646 | 20.829 | 74.914 | 62.095 | 1.00 | 9.98 | B | C |
| ATOM | 4389 | CD1 | LEU | B | 646 | 20.688 | 76.412 | 62.015 | 1.00 | 4.29 | B | C |
| ATOM | 4390 | CD2 | LEU | B | 646 | 20.026 | 74.247 | 60.976 | 1.00 | 4.82 | B | C |
| ATOM | 4391 | C | LEU | B | 646 | 24.000 | 72.775 | 61.513 | 1.00 | 15.06 | B | C |
| ATOM | 4392 | O | LEU | B | 646 | 25.078 | 73.049 | 62.038 | 1.00 | 14.88 | B | O |
| ATOM | 4393 | N | SER | B | 647 | 23.906 | 72.194 | 60.320 | 1.00 | 16.96 | B | N |
| ATOM | 4394 | CA | SER | B | 647 | 25.103 | 71.865 | 59.552 | 1.00 | 16.04 | B | C |
| ATOM | 4395 | CB | SER | B | 647 | 25.449 | 70.383 | 59.702 | 1.00 | 12.42 | B | C |
| ATOM | 4396 | OG | SER | B | 647 | 24.354 | 69.571 | 59.333 | 1.00 | 13.55 | B | O |
| ATOM | 4397 | C | SER | B | 647 | 24.975 | 72.221 | 58.073 | 1.00 | 17.39 | B | C |
| ATOM | 4398 | O | SER | B | 647 | 23.881 | 72.425 | 57.548 | 1.00 | 17.58 | B | O |
| ATOM | 4399 | N | THR | B | 648 | 26.124 | 72.260 | 57.411 | 1.00 | 17.40 | B | N |
| ATOM | 4400 | CA | THR | B | 648 | 26.238 | 72.624 | 56.008 | 1.00 | 17.37 | B | C |
| ATOM | 4401 | CB | THR | B | 648 | 27.585 | 73.375 | 55.832 | 1.00 | 18.58 | B | C |
| ATOM | 4402 | OG1 | THR | B | 648 | 27.376 | 74.588 | 55.109 | 1.00 | 22.21 | B | O |
| ATOM | 4403 | CG2 | THR | B | 648 | 28.606 | 72.511 | 55.146 | 1.00 | 16.87 | B | C |
| ATOM | 4404 | C | THR | B | 648 | 26.110 | 71.462 | 54.994 | 1.00 | 17.22 | B | C |
| ATOM | 4405 | O | THR | B | 648 | 25.455 | 71.604 | 53.957 | 1.00 | 16.25 | B | O |
| ATOM | 4406 | N | ASP | B | 649 | 26.721 | 70.320 | 55.307 | 1.00 | 16.97 | B | N |
| ATOM | 4407 | CA | ASP | B | 649 | 26.709 | 69.140 | 54.433 | 1.00 | 17.18 | B | C |
| ATOM | 4408 | CB | ASP | B | 649 | 25.297 | 68.867 | 53.907 | 1.00 | 16.57 | B | C |
| ATOM | 4409 | CG | ASP | B | 649 | 25.088 | 67.418 | 53.516 | 1.00 | 16.65 | B | C |
| ATOM | 4410 | OD1 | ASP | B | 649 | 26.011 | 66.592 | 53.718 | 1.00 | 18.29 | B | O |
| ATOM | 4411 | OD2 | ASP | B | 649 | 23.991 | 67.099 | 53.006 | 1.00 | 15.84 | B | O |
| ATOM | 4412 | C | ASP | B | 649 | 27.685 | 69.301 | 53.257 | 1.00 | 17.86 | B | C |
| ATOM | 4413 | O | ASP | B | 649 | 28.761 | 68.701 | 53.263 | 1.00 | 17.41 | B | O |
| ATOM | 4414 | N | ASP | B | 650 | 27.317 | 70.113 | 52.261 | 1.00 | 18.61 | B | N |
| ATOM | 4415 | CA | ASP | B | 650 | 28.162 | 70.349 | 51.078 | 1.00 | 18.78 | B | C |
| ATOM | 4416 | CB | ASP | B | 650 | 27.765 | 69.419 | 49.922 | 1.00 | 20.23 | B | C |
| ATOM | 4417 | CG | ASP | B | 650 | 27.918 | 67.952 | 50.267 | 1.00 | 21.79 | B | C |
| ATOM | 4418 | OD1 | ASP | B | 650 | 26.945 | 67.360 | 50.764 | 1.00 | 22.62 | B | O |
| ATOM | 4419 | OD2 | ASP | B | 650 | 29.008 | 67.385 | 50.042 | 1.00 | 24.07 | B | O |
| ATOM | 4420 | C | ASP | B | 650 | 28.049 | 71.793 | 50.592 | 1.00 | 18.16 | B | C |
| ATOM | 4421 | O | ASP | B | 650 | 27.273 | 72.089 | 49.687 | 1.00 | 18.07 | B | O |
| ATOM | 4422 | N | PRO | B | 651 | 28.843 | 72.704 | 51.173 | 1.00 | 17.29 | B | N |
| ATOM | 4423 | CD | PRO | B | 651 | 29.839 | 72.437 | 52.221 | 1.00 | 17.69 | B | C |
| ATOM | 4424 | CA | PRO | B | 651 | 28.815 | 74.119 | 50.789 | 1.00 | 18.48 | B | C |
| ATOM | 4425 | CB | PRO | B | 651 | 29.998 | 74.728 | 51.546 | 1.00 | 18.05 | B | C |
| ATOM | 4426 | CG | PRO | B | 651 | 30.263 | 73.805 | 52.653 | 1.00 | 18.72 | B | C |
| ATOM | 4427 | C | PRO | B | 651 | 28.929 | 74.350 | 49.284 | 1.00 | 18.66 | B | C |
| ATOM | 4428 | O | PRO | B | 651 | 28.216 | 75.179 | 48.721 | 1.00 | 19.23 | B | O |
| ATOM | 4429 | N | MET | B | 652 | 29.831 | 73.620 | 48.639 | 1.00 | 19.45 | B | N |
| ATOM | 4430 | CA | MET | B | 652 | 30.036 | 73.760 | 47.202 | 1.00 | 22.27 | B | C |
| ATOM | 4431 | CB | MET | B | 652 | 31.103 | 72.778 | 46.721 | 1.00 | 22.81 | B | C |
| ATOM | 4432 | CG | MET | B | 652 | 31.495 | 72.991 | 45.269 | 1.00 | 27.04 | B | C |
| ATOM | 4433 | SD | MET | B | 652 | 32.932 | 72.032 | 44.800 | 1.00 | 31.77 | B | S |
| ATOM | 4434 | CE | MET | B | 652 | 32.257 | 70.399 | 44.777 | 1.00 | 27.26 | B | C |
| ATOM | 4435 | C | MET | B | 652 | 28.759 | 73.555 | 46.388 | 1.00 | 21.04 | B | C |
| ATOM | 4436 | O | MET | B | 652 | 28.512 | 74.277 | 45.425 | 1.00 | 20.82 | B | O |
| ATOM | 4437 | N | GLN | B | 653 | 27.953 | 72.577 | 46.789 | 1.00 | 21.30 | B | N |
| ATOM | 4438 | CA | GLN | B | 653 | 26.708 | 72.262 | 46.098 | 1.00 | 21.67 | B | C |
| ATOM | 4439 | CB | GLN | B | 653 | 26.339 | 70.791 | 46.324 | 1.00 | 22.81 | B | C |
| ATOM | 4440 | CG | GLN | B | 653 | 26.867 | 69.818 | 45.298 | 1.00 | 27.81 | B | C |
| ATOM | 4441 | CD | GLN | B | 653 | 28.343 | 69.522 | 45.491 | 1.00 | 32.54 | B | C |
| ATOM | 4442 | OE1 | GLN | B | 653 | 29.151 | 69.693 | 44.571 | 1.00 | 34.58 | B | O |
| ATOM | 4443 | NE2 | GLN | B | 653 | 28.707 | 69.080 | 46.692 | 1.00 | 33.45 | B | N |
| ATOM | 4444 | C | GLN | B | 653 | 25.509 | 73.116 | 46.514 | 1.00 | 22.09 | B | C |
| ATOM | 4445 | O | GLN | B | 653 | 24.626 | 73.379 | 45.696 | 1.00 | 22.78 | B | O |
| ATOM | 4446 | N | PHE | B | 654 | 25.463 | 73.559 | 47.770 | 1.00 | 21.17 | B | N |
| ATOM | 4447 | CA | PHE | B | 654 | 24.296 | 74.311 | 48.231 | 1.00 | 19.49 | B | C |
| ATOM | 4448 | CB | PHE | B | 654 | 23.620 | 73.541 | 49.367 | 1.00 | 21.14 | B | C |
| ATOM | 4449 | CG | PHE | B | 654 | 23.547 | 72.054 | 49.149 | 1.00 | 20.48 | B | C |
| ATOM | 4450 | CD1 | PHE | B | 654 | 24.269 | 71.188 | 49.961 | 1.00 | 18.89 | B | C |
| ATOM | 4451 | CD2 | PHE | B | 654 | 22.734 | 71.519 | 48.152 | 1.00 | 19.27 | B | C |
| ATOM | 4452 | CE1 | PHE | B | 654 | 24.184 | 69.806 | 49.786 | 1.00 | 20.25 | B | C |
| ATOM | 4453 | CE2 | PHE | B | 654 | 22.640 | 70.143 | 47.966 | 1.00 | 20.08 | B | C |
| ATOM | 4454 | CZ | PHE | B | 654 | 23.368 | 69.280 | 48.788 | 1.00 | 21.34 | B | C |
| ATOM | 4455 | C | PHE | B | 654 | 24.402 | 75.770 | 48.674 | 1.00 | 18.77 | B | C |
| ATOM | 4456 | O | PHE | B | 654 | 23.383 | 76.445 | 48.786 | 1.00 | 17.88 | B | O |
| ATOM | 4457 | N | HIS | B | 655 | 25.600 | 76.281 | 48.916 | 1.00 | 20.22 | B | N |
| ATOM | 4458 | CA | HIS | B | 655 | 25.686 | 77.654 | 49.411 | 1.00 | 24.03 | B | C |
| ATOM | 4459 | CB | HIS | B | 655 | 26.464 | 77.636 | 50.731 | 1.00 | 22.86 | B | C |
| ATOM | 4460 | CG | HIS | B | 655 | 25.909 | 76.657 | 51.723 | 1.00 | 22.86 | B | C |
| ATOM | 4461 | CD2 | HIS | B | 655 | 26.034 | 75.313 | 51.810 | 1.00 | 20.56 | B | C |
| ATOM | 4462 | ND1 | HIS | B | 655 | 25.039 | 77.027 | 52.728 | 1.00 | 24.16 | B | N |
| ATOM | 4463 | CE1 | HIS | B | 655 | 24.650 | 75.950 | 53.388 | 1.00 | 21.19 | B | C |
| ATOM | 4464 | NE2 | HIS | B | 655 | 25.239 | 74.897 | 52.851 | 1.00 | 20.02 | B | N |
| ATOM | 4465 | C | HIS | B | 655 | 26.207 | 78.737 | 48.469 | 1.00 | 24.63 | B | C |
| ATOM | 4466 | O | HIS | B | 655 | 27.021 | 78.476 | 47.588 | 1.00 | 26.43 | B | O |
| ATOM | 4467 | N | PHE | B | 656 | 25.722 | 79.960 | 48.674 | 1.00 | 26.76 | B | N |
| ATOM | 4468 | CA | PHE | B | 656 | 26.085 | 81.102 | 47.835 | 1.00 | 29.45 | B | C |
| ATOM | 4469 | CB | PHE | B | 656 | 24.838 | 81.928 | 47.511 | 1.00 | 28.25 | B | C |
| ATOM | 4470 | CG | PHE | B | 656 | 23.796 | 81.186 | 46.728 | 1.00 | 29.43 | B | C |
| ATOM | 4471 | CD1 | PHE | B | 656 | 22.647 | 80.720 | 47.347 | 1.00 | 29.68 | B | C |
| ATOM | 4472 | CD2 | PHE | B | 656 | 23.950 | 80.969 | 45.363 | 1.00 | 31.84 | B | C |
| ATOM | 4473 | CE1 | PHE | B | 656 | 21.667 | 80.050 | 46.620 | 1.00 | 29.16 | B | C |
| ATOM | 4474 | CE2 | PHE | B | 656 | 22.970 | 80.297 | 44.628 | 1.00 | 30.41 | B | C |
| ATOM | 4475 | CZ | PHE | B | 656 | 21.831 | 79.840 | 45.258 | 1.00 | 29.08 | B | C |
| ATOM | 4476 | C | PHE | B | 656 | 27.141 | 82.062 | 48.377 | 1.00 | 31.91 | B | C |
| ATOM | 4477 | O | PHE | B | 656 | 27.657 | 82.886 | 47.620 | 1.00 | 33.50 | B | O |
| ATOM | 4478 | N | THR | B | 657 | 27.469 | 81.973 | 49.664 | 1.00 | 32.62 | B | N |
| ATOM | 4479 | CA | THR | B | 657 | 28.433 | 82.901 | 50.250 | 1.00 | 33.49 | B | C |
| ATOM | 4480 | CB | THR | B | 657 | 27.816 | 83.636 | 51.448 | 1.00 | 33.97 | B | C |
| ATOM | 4481 | OG1 | THR | B | 657 | 28.187 | 82.962 | 52.660 | 1.00 | 33.74 | B | O |
| ATOM | 4482 | CG2 | THR | B | 657 | 26.293 | 83.669 | 51.331 | 1.00 | 30.36 | B | C |
| ATOM | 4483 | C | THR | B | 657 | 29.735 | 82.269 | 50.715 | 1.00 | 36.44 | B | C |
| ATOM | 4484 | O | THR | B | 657 | 29.907 | 81.051 | 50.628 | 1.00 | 37.05 | B | O |
| ATOM | 4485 | N | LYS | B | 658 | 30.643 | 83.111 | 51.218 | 1.00 | 37.72 | B | N |
| ATOM | 4486 | CA | LYS | B | 658 | 31.949 | 82.659 | 51.708 | 1.00 | 38.74 | B | C |
| ATOM | 4487 | CB | LYS | B | 658 | 32.948 | 83.823 | 51.734 | 1.00 | 41.12 | B | C |
| ATOM | 4488 | CG | LYS | B | 658 | 33.390 | 84.317 | 50.355 | 1.00 | 44.99 | B | C |
| ATOM | 4489 | CD | LYS | B | 658 | 34.737 | 83.708 | 49.929 | 1.00 | 47.47 | B | C |
| ATOM | 4490 | CE | LYS | B | 658 | 34.806 | 83.477 | 48.413 | 1.00 | 47.53 | B | C |
| ATOM | 4491 | NZ | LYS | B | 658 | 34.749 | 82.034 | 48.051 | 1.00 | 45.70 | B | N |
| ATOM | 4492 | C | LYS | B | 658 | 31.822 | 82.081 | 53.110 | 1.00 | 37.96 | B | C |
| ATOM | 4493 | O | LYS | B | 658 | 32.753 | 81.463 | 53.629 | 1.00 | 38.69 | B | O |
| ATOM | 4494 | N | GLU | B | 659 | 30.664 | 82.289 | 53.723 | 1.00 | 37.14 | B | N |
| ATOM | 4495 | CA | GLU | B | 659 | 30.423 | 81.784 | 55.065 | 1.00 | 35.58 | B | C |
| ATOM | 4496 | CB | GLU | B | 659 | 30.323 | 82.955 | 56.044 | 1.00 | 37.95 | B | C |
| ATOM | 4497 | CG | GLU | B | 659 | 31.586 | 83.811 | 56.084 | 1.00 | 40.47 | B | C |
| ATOM | 4498 | CD | GLU | B | 659 | 31.588 | 84.801 | 57.233 | 1.00 | 42.88 | B | C |
| ATOM | 4499 | OE1 | GLU | B | 659 | 31.905 | 84.391 | 58.372 | 1.00 | 43.54 | B | O |
| ATOM | 4500 | OE2 | GLU | B | 659 | 31.273 | 85.989 | 56.999 | 1.00 | 45.46 | B | O |
| ATOM | 4501 | C | GLU | B | 659 | 29.143 | 80.955 | 55.076 | 1.00 | 32.51 | B | C |
| ATOM | 4502 | O | GLU | B | 659 | 28.101 | 81.392 | 55.569 | 1.00 | 31.45 | B | O |
| ATOM | 4503 | N | PRO | B | 660 | 29.210 | 79.738 | 54.511 | 1.00 | 30.56 | B | N |
| ATOM | 4504 | CD | PRO | B | 660 | 30.421 | 79.184 | 53.877 | 1.00 | 29.67 | B | C |
| ATOM | 4505 | CA | PRO | B | 660 | 28.072 | 78.813 | 54.434 | 1.00 | 27.12 | B | C |
| ATOM | 4506 | CB | PRO | B | 660 | 28.649 | 77.576 | 53.737 | 1.00 | 26.58 | B | C |
| ATOM | 4507 | CG | PRO | B | 660 | 30.136 | 77.717 | 53.835 | 1.00 | 28.57 | B | C |
| ATOM | 4508 | C | PRO | B | 660 | 27.385 | 78.467 | 55.764 | 1.00 | 24.05 | B | C |
| ATOM | 4509 | O | PRO | B | 660 | 26.164 | 78.323 | 55.800 | 1.00 | 22.69 | B | O |
| ATOM | 4510 | N | LEU | B | 661 | 28.152 | 78.329 | 56.847 | 1.00 | 21.90 | B | N |
| ATOM | 4511 | CA | LEU | B | 661 | 27.569 | 78.002 | 58.151 | 1.00 | 19.39 | B | C |
| ATOM | 4512 | CB | LEU | B | 661 | 28.660 | 77.713 | 59.188 | 1.00 | 19.50 | B | C |
| ATOM | 4513 | CG | LEU | B | 661 | 28.483 | 76.573 | 60.212 | 1.00 | 18.38 | B | C |
| ATOM | 4514 | CD1 | LEU | B | 661 | 28.850 | 77.072 | 61.588 | 1.00 | 15.17 | B | C |
| ATOM | 4515 | CD2 | LEU | B | 661 | 27.072 | 76.031 | 60.204 | 1.00 | 14.69 | B | C |
| ATOM | 4516 | C | LEU | B | 661 | 26.694 | 79.151 | 58.642 | 1.00 | 19.08 | B | C |
| ATOM | 4517 | O | LEU | B | 661 | 25.580 | 78.928 | 59.122 | 1.00 | 18.48 | B | O |
| ATOM | 4518 | N | MET | B | 662 | 27.199 | 80.375 | 58.518 | 1.00 | 19.24 | B | N |
| ATOM | 4519 | CA | MET | B | 662 | 26.451 | 81.562 | 58.933 | 1.00 | 20.36 | B | C |
| ATOM | 4520 | CB | MET | B | 662 | 27.316 | 82.820 | 58.796 | 1.00 | 22.79 | B | C |
| ATOM | 4521 | CG | MET | B | 662 | 28.450 | 82.919 | 59.817 | 1.00 | 28.50 | B | C |
| ATOM | 4522 | SD | MET | B | 662 | 27.889 | 82.835 | 61.554 | 1.00 | 36.57 | B | S |
| ATOM | 4523 | CE | MET | B | 662 | 26.680 | 84.175 | 61.594 | 1.00 | 33.20 | B | C |
| ATOM | 4524 | C | MET | B | 662 | 25.216 | 81.690 | 58.049 | 1.00 | 18.53 | B | C |
| ATOM | 4525 | O | MET | B | 662 | 24.169 | 82.177 | 58.476 | 1.00 | 15.92 | B | O |
| ATOM | 4526 | N | GLU | B | 663 | 25.355 | 81.242 | 56.807 | 1.00 | 18.03 | B | N |
| ATOM | 4527 | CA | GLU | B | 663 | 24.268 | 81.278 | 55.836 | 1.00 | 16.81 | B | C |
| ATOM | 4528 | CB | GLU | B | 663 | 24.799 | 80.887 | 54.455 | 1.00 | 19.10 | B | C |
| ATOM | 4529 | CG | GLU | B | 663 | 23.883 | 81.220 | 53.291 | 1.00 | 20.34 | B | C |
| ATOM | 4530 | CD | GLU | B | 663 | 24.479 | 80.791 | 51.952 | 1.00 | 22.49 | B | C |
| ATOM | 4531 | OE1 | GLU | B | 663 | 25.729 | 80.821 | 51.829 | 1.00 | 19.95 | B | O |
| ATOM | 4532 | OE2 | GLU | B | 663 | 23.696 | 80.422 | 51.037 | 1.00 | 19.92 | B | O |
| ATOM | 4533 | C | GLU | B | 663 | 23.164 | 80.317 | 56.259 | 1.00 | 15.87 | B | C |
| ATOM | 4534 | O | GLU | B | 663 | 21.986 | 80.676 | 56.223 | 1.00 | 14.23 | B | O |
| ATOM | 4535 | N | GLU | B | 664 | 23.544 | 79.099 | 56.654 | 1.00 | 15.14 | B | N |
| ATOM | 4536 | CA | GLU | B | 664 | 22.560 | 78.107 | 57.104 | 1.00 | 17.08 | B | C |
| ATOM | 4537 | CB | GLU | B | 664 | 23.227 | 76.779 | 57.474 | 1.00 | 16.40 | B | C |
| ATOM | 4538 | CG | GLU | B | 664 | 23.506 | 75.870 | 56.293 | 1.00 | 24.01 | B | C |
| ATOM | 4539 | CD | GLU | B | 664 | 22.400 | 74.863 | 56.006 | 1.00 | 23.21 | B | C |
| ATOM | 4540 | OE1 | GLU | B | 664 | 21.276 | 75.008 | 56.542 | 1.00 | 23.79 | B | O |
| ATOM | 4541 | OE2 | GLU | B | 664 | 22.666 | 73.921 | 55.226 | 1.00 | 25.92 | B | O |
| ATOM | 4542 | C | GLU | B | 664 | 21.807 | 78.625 | 58.323 | 1.00 | 16.58 | B | C |
| ATOM | 4543 | O | GLU | B | 664 | 20.592 | 78.460 | 58.422 | 1.00 | 17.27 | B | O |
| ATOM | 4544 | N | TYR | B | 665 | 22.540 | 79.238 | 59.252 | 1.00 | 14.93 | B | N |
| ATOM | 4545 | CA | TYR | B | 665 | 21.944 | 79.787 | 60.465 | 1.00 | 13.64 | B | C |
| ATOM | 4546 | CB | TYR | B | 665 | 23.033 | 80.290 | 61.421 | 1.00 | 14.59 | B | C |
| ATOM | 4547 | CG | TYR | B | 665 | 23.515 | 79.263 | 62.425 | 1.00 | 16.09 | B | C |
| ATOM | 4548 | CD1 | TYR | B | 665 | 24.512 | 78.347 | 62.090 | 1.00 | 14.67 | B | C |
| ATOM | 4549 | CE1 | TYR | B | 665 | 24.967 | 77.404 | 63.020 | 1.00 | 16.09 | B | C |
| ATOM | 4550 | CD2 | TYR | B | 665 | 22.983 | 79.214 | 63.723 | 1.00 | 17.28 | B | C |
| ATOM | 4551 | CE2 | TYR | B | 665 | 23.436 | 78.272 | 64.661 | 1.00 | 15.50 | B | C |
| ATOM | 4552 | CZ | TYR | B | 665 | 24.426 | 77.372 | 64.301 | 1.00 | 16.18 | B | C |
| ATOM | 4553 | OH | TYR | B | 665 | 24.876 | 76.427 | 65.201 | 1.00 | 15.48 | B | O |
| ATOM | 4554 | C | TYR | B | 665 | 21.013 | 80.941 | 60.122 | 1.00 | 13.63 | B | C |
| ATOM | 4555 | O | TYR | B | 665 | 19.914 | 81.036 | 60.659 | 1.00 | 14.03 | B | O |
| ATOM | 4556 | N | ALA | B | 666 | 21.456 | 81.816 | 59.220 | 1.00 | 14.19 | B | N |
| ATOM | 4557 | CA | ALA | B | 666 | 20.667 | 82.981 | 58.807 | 1.00 | 14.43 | B | C |
| ATOM | 4558 | CB | ALA | B | 666 | 21.481 | 83.854 | 57.864 | 1.00 | 13.04 | B | C |
| ATOM | 4559 | C | ALA | B | 666 | 19.321 | 82.660 | 58.167 | 1.00 | 13.23 | B | C |
| ATOM | 4560 | O | ALA | B | 666 | 18.306 | 83.222 | 58.546 | 1.00 | 13.14 | B | O |
| ATOM | 4561 | N | ILE | B | 667 | 19.297 | 81.759 | 57.196 | 1.00 | 14.85 | B | N |
| ATOM | 4562 | CA | ILE | B | 667 | 18.023 | 81.454 | 56.560 | 1.00 | 15.82 | B | C |
| ATOM | 4563 | CB | ILE | B | 667 | 18.197 | 80.621 | 55.256 | 1.00 | 16.56 | B | C |
| ATOM | 4564 | CG2 | ILE | B | 667 | 18.946 | 79.342 | 55.544 | 1.00 | 20.48 | B | C |
| ATOM | 4565 | CG1 | ILE | B | 667 | 16.826 | 80.302 | 54.656 | 1.00 | 16.86 | B | C |
| ATOM | 4566 | CD1 | ILE | B | 667 | 16.887 | 79.430 | 53.426 | 1.00 | 19.90 | B | C |
| ATOM | 4567 | C | ILE | B | 667 | 17.110 | 80.716 | 57.521 | 1.00 | 15.64 | B | C |
| ATOM | 4568 | O | ILE | B | 667 | 15.890 | 80.902 | 57.486 | 1.00 | 15.23 | B | O |
| ATOM | 4569 | N | ALA | B | 668 | 17.692 | 79.877 | 58.374 | 1.00 | 13.47 | B | N |
| ATOM | 4570 | CA | ALA | B | 668 | 16.893 | 79.139 | 59.351 | 1.00 | 14.79 | B | C |
| ATOM | 4571 | CB | ALA | B | 668 | 17.781 | 78.184 | 60.159 | 1.00 | 12.92 | B | C |
| ATOM | 4572 | C | ALA | B | 668 | 16.194 | 80.135 | 60.282 | 1.00 | 14.94 | B | C |
| ATOM | 4573 | O | ALA | B | 668 | 15.000 | 80.009 | 60.562 | 1.00 | 14.84 | B | O |
| ATOM | 4574 | N | ALA | B | 669 | 16.947 | 81.131 | 60.743 | 1.00 | 15.18 | B | N |
| ATOM | 4575 | CA | ALA | B | 669 | 16.414 | 82.159 | 61.630 | 1.00 | 15.21 | B | C |
| ATOM | 4576 | CB | ALA | B | 669 | 17.537 | 83.072 | 62.110 | 1.00 | 14.62 | B | C |
| ATOM | 4577 | C | ALA | B | 669 | 15.347 | 82.983 | 60.921 | 1.00 | 16.33 | B | C |
| ATOM | 4578 | O | ALA | B | 669 | 14.331 | 83.337 | 61.518 | 1.00 | 16.66 | B | O |
| ATOM | 4579 | N | GLN | B | 670 | 15.580 | 83.286 | 59.646 | 1.00 | 16.18 | B | N |
| ATOM | 4580 | CA | CLN | B | 670 | 14.631 | 84.076 | 58.868 | 1.00 | 16.89 | B | C |
| ATOM | 4581 | CB | GLN | B | 670 | 15.222 | 84.448 | 57.502 | 1.00 | 17.69 | B | C |
| ATOM | 4582 | CG | GLN | B | 670 | 16.584 | 85.104 | 57.558 | 1.00 | 21.86 | B | C |
| ATOM | 4583 | CD | GLN | B | 670 | 16.506 | 86.608 | 57.697 | 1.00 | 24.48 | B | C |
| ATOM | 4584 | OE1 | GLN | B | 670 | 15.510 | 87.148 | 58.188 | 1.00 | 26.37 | B | O |
| ATOM | 4585 | NE2 | GLN | B | 670 | 17.559 | 87.297 | 57.266 | 1.00 | 24.66 | B | N |
| ATOM | 4586 | C | GLN | B | 670 | 13.298 | 83.363 | 58.655 | 1.00 | 16.86 | B | C |
| ATOM | 4587 | O | GLN | B | 670 | 12.252 | 83.868 | 59.065 | 1.00 | 17.81 | B | O |
| ATOM | 4588 | N | VAL | B | 671 | 13.318 | 82.192 | 58.025 | 1.00 | 15.31 | B | N |
| ATOM | 4589 | CA | VAL | B | 671 | 12.062 | 81.499 | 57.775 | 1.00 | 16.80 | B | C |
| ATOM | 4590 | CB | VAL | B | 671 | 12.166 | 80.516 | 56.544 | 1.00 | 16.47 | B | C |
| ATOM | 4591 | CG1 | VAL | B | 671 | 13.470 | 80.718 | 55.814 | 1.00 | 16.16 | B | C |
| ATOM | 4592 | CG2 | VAL | B | 671 | 12.004 | 79.080 | 56.975 | 1.00 | 17.64 | B | C |
| ATOM | 4593 | C | VAL | B | 671 | 11.448 | 80.792 | 58.989 | 1.00 | 18.15 | B | C |
| ATOM | 4594 | O | VAL | B | 671 | 10.223 | 80.702 | 59.093 | 1.00 | 18.16 | B | O |
| ATOM | 4595 | N | PHE | B | 672 | 12.267 | 80.305 | 59.915 | 1.00 | 18.96 | B | N |
| ATOM | 4596 | CA | PHE | B | 672 | 11.706 | 79.641 | 61.089 | 1.00 | 19.89 | B | C |
| ATOM | 4597 | CB | PHE | B | 672 | 12.607 | 78.495 | 61.533 | 1.00 | 20.65 | B | C |
| ATOM | 4598 | CG | PHE | B | 672 | 12.574 | 77.328 | 60.599 | 1.00 | 21.51 | B | C |
| ATOM | 4599 | CD1 | PHE | B | 672 | 11.367 | 76.720 | 60.276 | 1.00 | 21.82 | B | C |
| ATOM | 4600 | CD2 | PHE | B | 672 | 13.738 | 76.861 | 60.002 | 1.00 | 23.60 | B | C |
| ATOM | 4601 | CE1 | PHE | B | 672 | 11.318 | 75.662 | 59.367 | 1.00 | 22.76 | B | C |
| ATOM | 4602 | CE2 | PHE | B | 672 | 13.700 | 75.804 | 59.091 | 1.00 | 23.75 | B | C |
| ATOM | 4603 | CZ | PHE | B | 672 | 12.487 | 75.205 | 58.773 | 1.00 | 22.43 | B | C |
| ATOM | 4604 | C | PHE | B | 672 | 11.466 | 80.613 | 62.235 | 1.00 | 20.15 | B | C |
| ATOM | 4605 | O | PHE | B | 672 | 10.930 | 80.239 | 63.269 | 1.00 | 21.88 | B | O |
| ATOM | 4606 | N | LYS | B | 673 | 11.858 | 81.865 | 62.027 | 1.00 | 20.29 | B | N |
| ATOM | 4607 | CA | LYS | B | 673 | 11.676 | 82.934 | 63.008 | 1.00 | 21.63 | B | C |
| ATOM | 4608 | CB | LYS | B | 673 | 10.184 | 83.283 | 63.137 | 1.00 | 21.69 | B | C |
| ATOM | 4609 | CG | LYS | B | 673 | 9.763 | 84.478 | 62.282 | 1.00 | 26.99 | B | C |
| ATOM | 4610 | CD | LYS | B | 673 | 8.376 | 84.317 | 61.685 | 1.00 | 29.28 | B | C |
| ATOM | 4611 | CE | LYS | B | 673 | 8.069 | 82.854 | 61.355 | 1.00 | 35.26 | B | C |
| ATOM | 4612 | NZ | LYS | B | 673 | 6.752 | 82.654 | 60.649 | 1.00 | 37.67 | B | N |
| ATOM | 4613 | C | LYS | B | 673 | 12.266 | 82.623 | 64.384 | 1.00 | 20.79 | B | C |
| ATOM | 4614 | O | LYS | B | 673 | 11.580 | 82.706 | 65.405 | 1.00 | 19.58 | B | O |
| ATOM | 4615 | N | LEU | B | 674 | 13.551 | 82.284 | 64.392 | 1.00 | 18.87 | B | N |
| ATOM | 4616 | CA | LEU | B | 674 | 14.279 | 81.956 | 65.615 | 1.00 | 17.72 | B | C |
| ATOM | 4617 | CB | LEU | B | 674 | 15.532 | 81.143 | 65.265 | 1.00 | 14.77 | B | C |
| ATOM | 4618 | CG | LEU | B | 674 | 15.479 | 79.613 | 65.189 | 1.00 | 16.34 | B | C |
| ATOM | 4619 | CD1 | LEU | B | 674 | 14.074 | 79.110 | 64.931 | 1.00 | 14.15 | B | C |
| ATOM | 4620 | CD2 | LEU | B | 674 | 16.422 | 79.163 | 64.099 | 1.00 | 17.42 | B | C |
| ATOM | 4621 | C | LEU | B | 674 | 14.712 | 83.208 | 66.372 | 1.00 | 16.57 | B | C |
| ATOM | 4622 | O | LEU | B | 674 | 15.127 | 84.187 | 65.756 | 1.00 | 18.14 | B | O |
| ATOM | 4623 | N | SER | B | 675 | 14.616 | 83.179 | 67.699 | 1.00 | 15.37 | B | N |
| ATOM | 4624 | CA | SER | B | 675 | 15.059 | 84.312 | 68.523 | 1.00 | 14.69 | B | C |
| ATOM | 4625 | CB | SER | B | 675 | 14.454 | 84.226 | 69.934 | 1.00 | 15.55 | B | C |
| ATOM | 4626 | OG | SER | B | 675 | 14.918 | 83.074 | 70.629 | 1.00 | 13.78 | B | O |
| ATOM | 4627 | C | SER | B | 675 | 16.574 | 84.148 | 68.608 | 1.00 | 14.49 | B | C |
| ATOM | 4628 | O | SER | B | 675 | 17.095 | 83.105 | 68.200 | 1.00 | 11.67 | B | O |
| ATOM | 4629 | N | THR | B | 676 | 17.295 | 85.143 | 69.118 | 1.00 | 15.62 | B | N |
| ATOM | 4630 | CA | THR | B | 676 | 18.743 | 84.976 | 69.204 | 1.00 | 18.58 | B | C |
| ATOM | 4631 | CB | THR | B | 676 | 19.490 | 86.326 | 69.413 | 1.00 | 19.62 | B | C |
| ATOM | 4632 | OG1 | THR | B | 676 | 20.214 | 86.290 | 70.645 | 1.00 | 25.69 | B | O |
| ATOM | 4633 | CG2 | THR | B | 676 | 18.526 | 87.490 | 69.405 | 1.00 | 21.59 | B | C |
| ATOM | 4634 | C | THR | B | 676 | 19.100 | 83.976 | 70.310 | 1.00 | 18.54 | B | C |
| ATOM | 4635 | O | THR | B | 676 | 20.202 | 83.421 | 70.324 | 1.00 | 20.62 | B | O |
| ATOM | 4636 | N | CYS | B | 677 | 18.160 | 83.729 | 71.223 | 1.00 | 17.47 | B | N |
| ATOM | 4637 | CA | CYS | B | 677 | 18.385 | 82.755 | 72.288 | 1.00 | 16.43 | B | C |
| ATOM | 4638 | CB | CYS | B | 677 | 17.349 | 82.903 | 73.414 | 1.00 | 15.70 | B | C |
| ATOM | 4639 | SG | CYS | B | 677 | 17.555 | 81.708 | 74.779 | 1.00 | 17.19 | B | S |
| ATOM | 4640 | C | CYS | B | 677 | 18.254 | 81.379 | 71.649 | 1.00 | 15.98 | B | C |
| ATOM | 4641 | O | CYS | B | 677 | 18.970 | 80.444 | 72.012 | 1.00 | 13.95 | B | O |
| ATOM | 4642 | N | ASP | B | 678 | 17.325 | 81.265 | 70.699 | 1.00 | 15.39 | B | N |
| ATOM | 4643 | CA | ASP | B | 678 | 17.102 | 80.017 | 69.963 | 1.00 | 15.73 | B | C |
| ATOM | 4644 | CB | ASP | B | 678 | 15.949 | 80.175 | 68.957 | 1.00 | 18.90 | B | C |
| ATOM | 4645 | CG | ASP | B | 678 | 14.576 | 80.228 | 69.621 | 1.00 | 22.39 | B | C |
| ATOM | 4646 | OD1 | ASP | B | 678 | 14.421 | 79.657 | 70.727 | 1.00 | 23.61 | B | O |
| ATOM | 4647 | OD2 | ASP | B | 678 | 13.650 | 80.836 | 69.031 | 1.00 | 19.08 | B | O |
| ATOM | 4648 | C | ASP | B | 678 | 18.372 | 79.689 | 69.183 | 1.00 | 14.93 | B | C |
| ATOM | 4649 | O | ASP | B | 678 | 18.826 | 78.550 | 69.154 | 1.00 | 15.13 | B | O |
| ATOM | 4650 | N | MET | B | 679 | 18.943 | 80.710 | 68.553 | 1.00 | 14.48 | B | N |
| ATOM | 4651 | CA | MET | B | 679 | 20.152 | 80.558 | 67.759 | 1.00 | 14.93 | B | C |
| ATOM | 4652 | CB | MET | B | 679 | 20.443 | 81.855 | 67.008 | 1.00 | 15.83 | B | C |
| ATOM | 4653 | CG | MET | B | 679 | 19.409 | 82.208 | 65.950 | 1.00 | 20.48 | B | C |
| ATOM | 4654 | SD | MET | B | 679 | 19.906 | 83.665 | 65.007 | 1.00 | 26.80 | B | S |
| ATOM | 4655 | CE | MET | B | 679 | 18.746 | 84.863 | 65.589 | 1.00 | 26.05 | B | C |
| ATOM | 4656 | C | MET | B | 679 | 21.363 | 80.188 | 68.595 | 1.00 | 14.76 | B | C |
| ATOM | 4657 | O | MET | B | 679 | 22.176 | 79.368 | 68.191 | 1.00 | 15.27 | B | O |
| ATOM | 4658 | N | CYS | B | 680 | 21.499 | 80.810 | 69.759 | 1.00 | 16.24 | B | N |
| ATOM | 4659 | CA | CYS | B | 680 | 22.635 | 80.521 | 70.623 | 1.00 | 16.23 | B | C |
| ATOM | 4660 | CB | CYS | B | 680 | 22.776 | 81.616 | 71.678 | 1.00 | 17.42 | B | C |
| ATOM | 4661 | SG | CYS | B | 680 | 23.264 | 83.211 | 70.954 | 1.00 | 23.22 | B | S |
| ATOM | 4662 | C | CYS | B | 680 | 22.523 | 79.144 | 71.277 | 1.00 | 14.90 | B | C |
| ATOM | 4663 | O | CYS | B | 680 | 23.533 | 78.549 | 71.658 | 1.00 | 15.26 | B | O |
| ATOM | 4664 | N | GLU | B | 681 | 21.302 | 78.633 | 71.400 | 1.00 | 12.86 | B | N |
| ATOM | 4665 | CA | GLU | B | 681 | 21.106 | 77.309 | 71.977 | 1.00 | 12.99 | B | C |
| ATOM | 4666 | CB | GLU | B | 681 | 19.635 | 77.076 | 72.344 | 1.00 | 11.97 | B | C |
| ATOM | 4667 | CG | GLU | B | 681 | 19.422 | 75.829 | 73.207 | 1.00 | 13.80 | B | C |
| ATOM | 4668 | CD | GLU | B | 681 | 17.956 | 75.506 | 73.506 | 1.00 | 15.87 | B | C |
| ATOM | 4669 | OE1 | GLU | B | 681 | 17.051 | 76.254 | 73.075 | 1.00 | 15.65 | B | O |
| ATOM | 4670 | OE2 | GLU | B | 681 | 17.709 | 74.485 | 74.185 | 1.00 | 14.38 | B | O |
| ATOM | 4671 | C | GLU | B | 681 | 21.561 | 76.263 | 70.952 | 1.00 | 14.58 | B | C |
| ATOM | 4672 | O | GLU | B | 681 | 22.180 | 75.254 | 71.304 | 1.00 | 15.33 | B | O |
| ATOM | 4673 | N | VAL | B | 682 | 21.259 | 76.508 | 69.680 | 1.00 | 13.22 | B | N |
| ATOM | 4674 | CA | VAL | B | 682 | 21.661 | 75.584 | 68.622 | 1.00 | 11.64 | B | C |
| ATOM | 4675 | CB | VAL | B | 682 | 21.079 | 76.010 | 67.247 | 1.00 | 12.39 | B | C |
| ATOM | 4676 | CG1 | VAL | B | 682 | 21.783 | 75.260 | 66.123 | 1.00 | 10.45 | B | C |
| ATOM | 4677 | CG2 | VAL | B | 682 | 19.570 | 75.740 | 67.216 | 1.00 | 7.49 | B | C |
| ATOM | 4678 | C | VAL | B | 682 | 23.186 | 75.546 | 68.543 | 1.00 | 11.37 | B | C |
| ATOM | 4679 | O | VAL | B | 682 | 23.782 | 74.476 | 68.423 | 1.00 | 13.69 | B | O |
| ATOM | 4680 | N | ALA | B | 683 | 23.808 | 76.722 | 68.620 | 1.00 | 9.93 | B | N |
| ATOM | 4681 | CA | ALA | B | 683 | 25.261 | 76.847 | 68.578 | 1.00 | 9.85 | B | C |
| ATOM | 4682 | CB | ALA | B | 683 | 25.653 | 78.307 | 68.679 | 1.00 | 9.53 | B | C |
| ATOM | 4683 | C | ALA | B | 683 | 25.919 | 76.057 | 69.703 | 1.00 | 11.08 | B | C |
| ATOM | 4684 | O | ALA | B | 683 | 26.906 | 75.357 | 69.492 | 1.00 | 11.25 | B | O |
| ATOM | 4685 | N | ARG | B | 684 | 25.371 | 76.182 | 70.908 | 1.00 | 13.72 | B | N |
| ATOM | 4686 | CA | ARG | B | 684 | 25.900 | 75.476 | 72.068 | 1.00 | 13.57 | B | C |
| ATOM | 4687 | CB | ARG | B | 684 | 25.112 | 75.869 | 73.324 | 1.00 | 13.52 | B | C |
| ATOM | 4688 | CG | ARG | B | 684 | 25.518 | 75.127 | 74.580 | 1.00 | 14.89 | B | C |
| ATOM | 4689 | CD | ARG | B | 684 | 24.898 | 75.777 | 75.819 | 1.00 | 16.52 | B | C |
| ATOM | 4690 | NE | ARG | B | 684 | 25.483 | 75.251 | 77.049 | 1.00 | 16.96 | B | N |
| ATOM | 4691 | CZ | ARG | B | 684 | 25.093 | 74.128 | 77.642 | 1.00 | 15.91 | B | C |
| ATOM | 4692 | NH1 | ARG | B | 684 | 24.110 | 73.405 | 77.122 | 1.00 | 15.83 | B | N |
| ATOM | 4693 | NH2 | ARG | B | 684 | 25.707 | 73.714 | 78.741 | 1.00 | 15.54 | B | N |
| ATOM | 4694 | C | ARG | B | 684 | 25.783 | 73.980 | 71.827 | 1.00 | 13.65 | B | C |
| ATOM | 4695 | O | ARG | B | 684 | 26.712 | 73.218 | 72.107 | 1.00 | 14.92 | B | O |
| ATOM | 4696 | N | ASN | B | 685 | 24.633 | 73.557 | 71.315 | 1.00 | 12.78 | B | N |
| ATOM | 4697 | CA | ASN | B | 685 | 24.412 | 72.147 | 71.027 | 1.00 | 13.18 | B | C |
| ATOM | 4698 | CB | ASN | B | 685 | 23.043 | 71.947 | 70.380 | 1.00 | 15.86 | B | C |
| ATOM | 4699 | CG | ASN | B | 685 | 21.909 | 72.036 | 71.375 | 1.00 | 18.56 | B | C |
| ATOM | 4700 | OD1 | ASN | B | 685 | 22.130 | 72.250 | 72.564 | 1.00 | 20.13 | B | O |
| ATOM | 4701 | ND2 | ASN | B | 685 | 20.682 | 71.871 | 70.892 | 1.00 | 16.45 | B | N |
| ATOM | 4702 | C | ASN | B | 685 | 25.483 | 71.616 | 70.075 | 1.00 | 13.68 | B | C |
| ATOM | 4703 | O | ASN | B | 685 | 25.979 | 70.503 | 70.237 | 1.00 | 13.49 | B | O |
| ATOM | 4704 | N | SER | B | 686 | 25.841 | 72.419 | 69.077 | 1.00 | 14.09 | B | N |
| ATOM | 4705 | CA | SER | B | 686 | 26.834 | 71.996 | 68.098 | 1.00 | 13.83 | B | C |
| ATOM | 4706 | CB | SER | B | 686 | 26.908 | 73.010 | 66.938 | 1.00 | 10.64 | B | C |
| ATOM | 4707 | OG | SER | B | 686 | 27.713 | 74.137 | 67.235 | 1.00 | 11.40 | B | O |
| ATOM | 4708 | C | SER | B | 686 | 28.199 | 71.771 | 68.733 | 1.00 | 13.81 | B | C |
| ATOM | 4709 | O | SER | B | 686 | 28.905 | 70.828 | 68.369 | 1.00 | 14.43 | B | O |
| ATOM | 4710 | N | VAL | B | 687 | 28.569 | 72.619 | 69.690 | 1.00 | 13.95 | B | N |
| ATOM | 4711 | CA | VAL | B | 687 | 29.853 | 72.462 | 70.369 | 1.00 | 14.34 | B | C |
| ATOM | 4712 | CB | VAL | B | 687 | 30.185 | 73.681 | 71.256 | 1.00 | 15.89 | B | C |
| ATOM | 4713 | CG1 | VAL | B | 687 | 31.541 | 73.479 | 71.933 | 1.00 | 14.11 | B | C |
| ATOM | 4714 | CG2 | VAL | B | 687 | 30.210 | 74.952 | 70.406 | 1.00 | 14.65 | B | C |
| ATOM | 4715 | C | VAL | B | 687 | 29.836 | 71.211 | 71.241 | 1.00 | 14.72 | B | C |
| ATOM | 4716 | O | VAL | B | 687 | 30.810 | 70.467 | 71.295 | 1.00 | 15.84 | B | O |
| ATOM | 4717 | N | LEU | B | 688 | 28.721 | 70.982 | 71.923 | 1.00 | 15.16 | B | N |
| ATOM | 4718 | CA | LEU | B | 688 | 28.586 | 69.812 | 72.784 | 1.00 | 15.56 | B | C |
| ATOM | 4719 | CB | LEU | B | 688 | 27.247 | 69.858 | 73.543 | 1.00 | 13.58 | B | C |
| ATOM | 4720 | CG | LEU | B | 688 | 27.082 | 70.899 | 74.664 | 1.00 | 14.26 | B | C |
| ATOM | 4721 | CD1 | LEU | B | 688 | 25.632 | 70.926 | 75.144 | 1.00 | 13.67 | B | C |
| ATOM | 4722 | CD2 | LEU | B | 688 | 28.020 | 70.562 | 75.809 | 1.00 | 12.14 | B | C |
| ATOM | 4723 | C | LEU | B | 688 | 28.655 | 68.523 | 71.960 | 1.00 | 16.04 | B | C |
| ATOM | 4724 | O | LEU | B | 688 | 29.255 | 67.525 | 72.377 | 1.00 | 18.23 | B | O |
| ATOM | 4725 | N | GLN | B | 689 | 28.039 | 68.555 | 70.784 | 1.00 | 15.23 | B | N |
| ATOM | 4726 | CA | GLN | B | 689 | 27.988 | 67.399 | 69.899 | 1.00 | 14.06 | B | C |
| ATOM | 4727 | CB | GLN | B | 689 | 26.921 | 67.635 | 68.828 | 1.00 | 12.47 | B | C |
| ATOM | 4728 | CG | GLN | B | 689 | 26.922 | 66.604 | 67.722 | 1.00 | 11.28 | B | C |
| ATOM | 4729 | CD | GLN | B | 689 | 25.754 | 66.757 | 66.780 | 1.00 | 11.26 | B | C |
| ATOM | 4730 | OE1 | GLN | B | 689 | 25.451 | 65.855 | 66.004 | 1.00 | 13.75 | B | O |
| ATOM | 4731 | NE2 | GLN | B | 689 | 25.092 | 67.898 | 66.837 | 1.00 | 10.62 | B | N |
| ATOM | 4732 | C | GLN | B | 689 | 29.306 | 67.020 | 69.211 | 1.00 | 13.93 | B | C |
| ATOM | 4733 | O | GLN | B | 689 | 29.630 | 65.838 | 69.084 | 1.00 | 12.97 | B | O |
| ATOM | 4734 | N | CYS | B | 690 | 30.062 | 68.024 | 68.779 | 1.00 | 15.86 | B | N |
| ATOM | 4735 | CA | CYS | B | 690 | 31.304 | 67.794 | 68.049 | 1.00 | 17.35 | B | C |
| ATOM | 4736 | CB | CYS | B | 690 | 31.827 | 69.120 | 67.502 | 1.00 | 16.42 | B | C |
| ATOM | 4737 | SG | CYS | B | 690 | 32.614 | 70.181 | 68.720 | 1.00 | 21.13 | B | S |
| ATOM | 4738 | C | CYS | B | 690 | 32.426 | 67.055 | 68.771 | 1.00 | 19.51 | B | C |
| ATOM | 4739 | O | CYS | B | 690 | 32.316 | 66.730 | 69.956 | 1.00 | 21.25 | B | O |
| ATOM | 4740 | N | GLY | B | 691 | 33.507 | 66.792 | 68.036 | 1.00 | 17.66 | B | N |
| ATOM | 4741 | CA | GLY | B | 691 | 34.642 | 66.077 | 68.587 | 1.00 | 17.20 | B | C |
| ATOM | 4742 | C | GLY | B | 691 | 35.816 | 66.935 | 69.017 | 1.00 | 18.23 | B | C |
| ATOM | 4743 | O | GLY | B | 691 | 36.925 | 66.427 | 69.180 | 1.00 | 20.48 | B | O |
| ATOM | 4744 | N | ILE | B | 692 | 35.586 | 68.231 | 69.199 | 1.00 | 17.82 | B | N |
| ATOM | 4745 | CA | ILE | B | 692 | 36.642 | 69.142 | 69.632 | 1.00 | 17.28 | B | C |
| ATOM | 4746 | CB | ILE | B | 692 | 36.097 | 70.581 | 69.715 | 1.00 | 17.60 | B | C |
| ATOM | 4747 | CG2 | ILE | B | 692 | 37.011 | 71.458 | 70.554 | 1.00 | 17.31 | B | C |
| ATOM | 4748 | CG1 | ILE | B | 692 | 35.962 | 71.152 | 68.302 | 1.00 | 17.96 | B | C |
| ATOM | 4749 | CD1 | ILE | B | 692 | 35.538 | 72.620 | 68.248 | 1.00 | 18.23 | B | C |
| ATOM | 4750 | C | ILE | B | 692 | 37.148 | 68.684 | 71.009 | 1.00 | 18.08 | B | C |
| ATOM | 4751 | O | ILE | B | 692 | 36.414 | 68.031 | 71.752 | 1.00 | 17.59 | B | O |
| ATOM | 4752 | N | SER | B | 693 | 38.393 | 69.022 | 71.348 | 1.00 | 18.91 | B | N |
| ATOM | 4753 | CA | SER | B | 693 | 38.979 | 68.615 | 72.628 | 1.00 | 19.51 | B | C |
| ATOM | 4754 | CB | SER | B | 693 | 40.460 | 68.995 | 72.678 | 1.00 | 18.64 | B | C |
| ATOM | 4755 | OG | SER | B | 693 | 40.634 | 70.383 | 72.899 | 1.00 | 19.40 | B | O |
| ATOM | 4756 | C | SER | B | 693 | 38.265 | 69.169 | 73.868 | 1.00 | 20.10 | B | C |
| ATOM | 4757 | O | SER | B | 693 | 37.593 | 70.208 | 73.815 | 1.00 | 17.80 | B | O |
| ATOM | 4758 | N | HIS | B | 694 | 38.417 | 68.459 | 74.984 | 1.00 | 23.42 | B | N |
| ATOM | 4759 | CA | HIS | B | 694 | 37.797 | 68.855 | 76.246 | 1.00 | 26.08 | B | C |
| ATOM | 4760 | CB | HIS | B | 694 | 38.083 | 67.824 | 77.337 | 1.00 | 27.13 | B | C |
| ATOM | 4761 | CG | HIS | B | 694 | 37.546 | 68.216 | 78.679 | 1.00 | 30.20 | B | C |
| ATOM | 4762 | CD2 | HIS | B | 694 | 36.318 | 68.059 | 79.228 | 1.00 | 30.28 | B | C |
| ATOM | 4763 | ND1 | HIS | B | 694 | 38.297 | 68.901 | 79.611 | 1.00 | 30.55 | B | N |
| ATOM | 4764 | CE1 | HIS | B | 694 | 37.553 | 69.152 | 80.673 | 1.00 | 30.07 | B | C |
| ATOM | 4765 | NE2 | HIS | B | 694 | 36.349 | 68.651 | 80.467 | 1.00 | 29.92 | B | N |
| ATOM | 4766 | C | HIS | B | 694 | 38.285 | 70.215 | 76.721 | 1.00 | 27.45 | B | C |
| ATOM | 4767 | O | HIS | B | 694 | 37.493 | 71.054 | 77.149 | 1.00 | 28.31 | B | O |
| ATOM | 4768 | N | GLU | B | 695 | 39.592 | 70.426 | 76.650 | 1.00 | 29.12 | B | N |
| ATOM | 4769 | CA | GLU | B | 695 | 40.183 | 71.687 | 77.073 | 1.00 | 32.90 | B | C |
| ATOM | 4770 | CB | GLU | B | 695 | 41.711 | 71.633 | 76.918 | 1.00 | 38.64 | B | C |
| ATOM | 4771 | CG | GLU | B | 695 | 42.444 | 72.917 | 77.345 | 1.00 | 47.73 | B | C |
| ATOM | 4772 | CD | GLU | B | 695 | 43.496 | 73.388 | 76.328 | 1.00 | 53.11 | B | C |
| ATOM | 4773 | OE1 | GLU | B | 695 | 44.643 | 72.879 | 76.366 | 1.00 | 56.16 | B | O |
| ATOM | 4774 | OE2 | GLU | B | 695 | 43.176 | 74.272 | 75.495 | 1.00 | 55.10 | B | O |
| ATOM | 4775 | C | GLU | B | 695 | 39.618 | 72.849 | 76.262 | 1.00 | 32.09 | B | C |
| ATOM | 4776 | O | GLU | B | 695 | 39.350 | 73.922 | 76.802 | 1.00 | 32.79 | B | O |
| ATOM | 4777 | N | GLU | B | 696 | 39.429 | 72.631 | 74.964 | 1.00 | 30.36 | B | N |
| ATOM | 4778 | CA | GLU | B | 696 | 38.905 | 73.679 | 74.102 | 1.00 | 28.16 | B | C |
| ATOM | 4779 | CB | GLU | B | 696 | 39.127 | 73.313 | 72.646 | 1.00 | 29.12 | B | C |
| ATOM | 4780 | CG | GLU | B | 696 | 40.388 | 73.912 | 72.073 | 1.00 | 33.77 | B | C |
| ATOM | 4781 | CD | GLU | B | 696 | 40.779 | 73.259 | 70.769 | 1.00 | 36.85 | B | C |
| ATOM | 4782 | OE1 | GLU | B | 696 | 40.692 | 73.939 | 69.715 | 1.00 | 37.42 | B | O |
| ATOM | 4783 | OE2 | GLU | B | 696 | 41.165 | 72.063 | 70.805 | 1.00 | 37.76 | B | O |
| ATOM | 4784 | C | GLU | B | 696 | 37.431 | 73.941 | 74.345 | 1.00 | 25.18 | B | C |
| ATOM | 4785 | O | GLU | B | 696 | 36.996 | 75.089 | 74.362 | 1.00 | 24.89 | B | O |
| ATOM | 4786 | N | LYS | B | 697 | 36.661 | 72.875 | 74.530 | 1.00 | 24.20 | B | N |
| ATOM | 4787 | CA | LYS | B | 697 | 35.233 | 73.010 | 74.788 | 1.00 | 22.96 | B | C |
| ATOM | 4788 | CB | LYS | B | 697 | 34.591 | 71.635 | 74.908 | 1.00 | 20.95 | B | C |
| ATOM | 4789 | CG | LYS | B | 697 | 34.392 | 70.924 | 73.586 | 1.00 | 20.81 | B | C |
| ATOM | 4790 | CD | LYS | B | 697 | 33.295 | 69.882 | 73.700 | 1.00 | 16.82 | B | C |
| ATOM | 4791 | CE | LYS | B | 697 | 33.290 | 68.961 | 72.503 | 1.00 | 17.66 | B | C |
| ATOM | 4792 | NZ | LYS | B | 697 | 32.154 | 68.009 | 72.573 | 1.00 | 17.05 | B | N |
| ATOM | 4793 | C | LYS | B | 697 | 34.972 | 73.798 | 76.074 | 1.00 | 25.05 | B | C |
| ATOM | 4794 | O | LYS | B | 697 | 34.072 | 74.638 | 76.126 | 1.00 | 26.16 | B | O |
| ATOM | 4795 | N | ALA | B | 698 | 35.757 | 73.515 | 77.111 | 1.00 | 25.33 | B | N |
| ATOM | 4796 | CA | ALA | B | 698 | 35.614 | 74.191 | 78.392 | 1.00 | 24.59 | B | C |
| ATOM | 4797 | CB | ALA | B | 698 | 36.593 | 73.609 | 79.395 | 1.00 | 25.22 | B | C |
| ATOM | 4798 | C | ALA | B | 698 | 35.880 | 75.676 | 78.204 | 1.00 | 26.05 | B | C |
| ATOM | 4799 | O | ALA | B | 698 | 35.295 | 76.522 | 78.884 | 1.00 | 27.56 | B | O |
| ATOM | 4800 | N | LYS | B | 699 | 36.767 | 75.986 | 77.267 | 1.00 | 25.91 | B | N |
| ATOM | 4801 | CA | LYS | B | 699 | 37.130 | 77.362 | 76.967 | 1.00 | 24.98 | B | C |
| ATOM | 4802 | CB | LYS | B | 699 | 38.453 | 77.373 | 76.190 | 1.00 | 27.38 | B | C |
| ATOM | 4803 | CG | LYS | B | 699 | 38.691 | 78.577 | 75.296 | 1.00 | 32.67 | B | C |
| ATOM | 4804 | CD | LYS | B | 699 | 39.965 | 78.382 | 74.464 | 1.00 | 35.73 | B | C |
| ATOM | 4805 | CE | LYS | B | 699 | 40.072 | 79.391 | 73.321 | 1.00 | 35.75 | B | C |
| ATOM | 4806 | NZ | LYS | B | 699 | 39.838 | 80.792 | 73.779 | 1.00 | 37.60 | B | N |
| ATOM | 4807 | C | LYS | B | 699 | 36.026 | 78.065 | 76.178 | 1.00 | 24.01 | B | C |
| ATOM | 4808 | O | LYS | B | 699 | 35.858 | 79.281 | 76.281 | 1.00 | 23.24 | B | O |
| ATOM | 4809 | N | PHE | B | 700 | 35.267 | 77.293 | 75.404 | 1.00 | 22.46 | B | N |
| ATOM | 4810 | CA | PHE | B | 700 | 34.182 | 77.845 | 74.590 | 1.00 | 21.88 | B | C |
| ATOM | 4811 | CB | PHE | B | 700 | 33.943 | 76.983 | 73.340 | 1.00 | 20.39 | B | C |
| ATOM | 4812 | CG | PHE | B | 700 | 35.119 | 76.906 | 72.403 | 1.00 | 19.16 | B | C |
| ATOM | 4813 | CD1 | PHE | B | 700 | 36.106 | 77.884 | 72.407 | 1.00 | 17.65 | B | C |
| ATOM | 4814 | CD2 | PHE | B | 700 | 35.244 | 75.830 | 71.522 | 1.00 | 18.22 | B | C |
| ATOM | 4815 | CE1 | PHE | B | 700 | 37.206 | 77.794 | 71.553 | 1.00 | 17.23 | B | C |
| ATOM | 4816 | CE2 | PHE | B | 700 | 36.340 | 75.730 | 70.664 | 1.00 | 18.81 | B | C |
| ATOM | 4817 | CZ | PHE | B | 700 | 37.323 | 76.716 | 70.683 | 1.00 | 17.21 | B | C |
| ATOM | 4818 | C | PHE | B | 700 | 32.867 | 77.935 | 75.343 | 1.00 | 21.15 | B | C |
| ATOM | 4819 | O | PHE | B | 700 | 32.137 | 78.911 | 75.204 | 1.00 | 18.55 | B | O |
| ATOM | 4820 | N | LEU | B | 701 | 32.574 | 76.904 | 76.133 | 1.00 | 22.50 | B | N |
| ATOM | 4821 | CA | LEU | B | 701 | 31.323 | 76.814 | 76.884 | 1.00 | 23.25 | B | C |
| ATOM | 4822 | CB | LEU | B | 701 | 30.692 | 75.442 | 76.641 | 1.00 | 20.01 | B | C |
| ATOM | 4823 | CG | LEU | B | 701 | 30.540 | 74.980 | 75.197 | 1.00 | 18.79 | B | C |
| ATOM | 4824 | CD1 | LEU | B | 701 | 30.057 | 73.543 | 75.174 | 1.00 | 17.60 | B | C |
| ATOM | 4825 | CD2 | LEU | B | 701 | 29.554 | 75.887 | 74.481 | 1.00 | 18.86 | B | C |
| ATOM | 4826 | C | LEU | B | 701 | 31.389 | 77.042 | 78.394 | 1.00 | 24.60 | B | C |
| ATOM | 4827 | O | LEU | B | 701 | 30.362 | 77.281 | 79.029 | 1.00 | 25.49 | B | O |
| ATOM | 4828 | N | GLY | B | 702 | 32.583 | 76.955 | 78.966 | 1.00 | 26.40 | B | N |
| ATOM | 4829 | CA | GLY | B | 702 | 32.730 | 77.116 | 80.402 | 1.00 | 26.52 | B | C |
| ATOM | 4830 | C | GLY | B | 702 | 33.238 | 75.801 | 80.967 | 1.00 | 28.14 | B | C |
| ATOM | 4831 | O | GLY | B | 702 | 33.002 | 74.739 | 80.381 | 1.00 | 28.77 | B | O |
| ATOM | 4832 | N | ASN | B | 703 | 33.918 | 75.857 | 82.107 | 1.00 | 28.31 | B | N |
| ATOM | 4833 | CA | ASN | B | 703 | 34.492 | 74.661 | 82.716 | 1.00 | 28.57 | B | C |
| ATOM | 4834 | CB | ASN | B | 703 | 35.420 | 75.070 | 83.856 | 1.00 | 30.99 | B | C |
| ATOM | 4835 | CG | ASN | B | 703 | 36.541 | 75.968 | 83.389 | 1.00 | 33.61 | B | C |
| ATOM | 4836 | OD1 | ASN | B | 703 | 37.578 | 75.496 | 82.918 | 1.00 | 34.91 | B | O |
| ATOM | 4837 | ND2 | ASN | B | 703 | 36.337 | 77.273 | 83.505 | 1.00 | 35.86 | B | N |
| ATOM | 4838 | C | ASN | B | 703 | 33.546 | 73.577 | 83.212 | 1.00 | 28.07 | B | C |
| ATOM | 4839 | O | ASN | B | 703 | 33.975 | 72.449 | 83.432 | 1.00 | 28.72 | B | O |
| ATOM | 4840 | N | ASN | B | 704 | 32.269 | 73.897 | 83.379 | 1.00 | 27.95 | B | N |
| ATOM | 4841 | CA | ASN | B | 704 | 31.302 | 72.917 | 83.874 | 1.00 | 26.98 | B | C |
| ATOM | 4842 | CB | ASN | B | 704 | 30.459 | 73.545 | 84.979 | 1.00 | 31.15 | B | C |
| ATOM | 4843 | CG | ASN | B | 704 | 30.679 | 72.887 | 86.321 | 1.00 | 35.66 | B | C |
| ATOM | 4844 | OD1 | ASN | B | 704 | 30.040 | 71.879 | 86.645 | 1.00 | 36.74 | B | O |
| ATOM | 4845 | ND2 | ASN | B | 704 | 31.589 | 73.454 | 87.114 | 1.00 | 36.73 | B | N |
| ATOM | 4846 | C | ASN | B | 704 | 30.372 | 72.388 | 82.798 | 1.00 | 24.93 | B | C |
| ATOM | 4847 | O | ASN | B | 704 | 29.373 | 71.730 | 83.099 | 1.00 | 23.56 | B | O |
| ATOM | 4848 | N | TYR | B | 705 | 30.710 | 72.664 | 81.546 | 1.00 | 23.69 | B | N |
| ATOM | 4849 | CA | TYR | B | 705 | 29.884 | 72.261 | 80.410 | 1.00 | 22.88 | B | C |
| ATOM | 4850 | CB | TYR | B | 705 | 30.606 | 72.633 | 79.104 | 1.00 | 21.43 | B | C |
| ATOM | 4851 | CG | TYR | B | 705 | 31.613 | 71.616 | 78.624 | 1.00 | 18.14 | B | C |
| ATOM | 4852 | CD1 | TYR | B | 705 | 32.950 | 71.709 | 78.987 | 1.00 | 17.19 | B | C |
| ATOM | 4853 | CE1 | TYR | B | 705 | 33.877 | 70.766 | 78.554 | 1.00 | 17.54 | B | C |
| ATOM | 4854 | CD2 | TYR | B | 705 | 31.221 | 70.550 | 77.807 | 1.00 | 17.62 | B | C |
| ATOM | 4855 | CE2 | TYR | B | 705 | 32.137 | 69.607 | 77.371 | 1.00 | 15.92 | B | C |
| ATOM | 4856 | CZ | TYR | B | 705 | 33.463 | 69.719 | 77.748 | 1.00 | 17.01 | B | C |
| ATOM | 4857 | OH | TYR | B | 705 | 34.374 | 68.778 | 77.324 | 1.00 | 19.24 | B | O |
| ATOM | 4858 | C | TYR | B | 705 | 29.416 | 70.797 | 80.377 | 1.00 | 22.88 | B | C |
| ATOM | 4859 | O | TYR | B | 705 | 28.380 | 70.488 | 79.781 | 1.00 | 23.00 | B | O |
| ATOM | 4860 | N | LEU | B | 706 | 30.155 | 69.899 | 81.022 | 1.00 | 22.71 | B | N |
| ATOM | 4861 | CA | LEU | B | 706 | 29.772 | 68.490 | 81.028 | 1.00 | 22.74 | B | C |
| ATOM | 4862 | CB | LEU | B | 706 | 30.975 | 67.611 | 81.402 | 1.00 | 22.67 | B | C |
| ATOM | 4863 | CG | LEU | B | 706 | 32.005 | 67.315 | 80.301 | 1.00 | 22.84 | B | C |
| ATOM | 4864 | CD1 | LEU | B | 706 | 33.274 | 66.748 | 80.912 | 1.00 | 21.31 | B | C |
| ATOM | 4865 | CD2 | LEU | B | 706 | 31.420 | 66.331 | 79.298 | 1.00 | 23.62 | B | C |
| ATOM | 4866 | C | LEU | B | 706 | 28.607 | 68.216 | 81.980 | 1.00 | 24.33 | B | C |
| ATOM | 4867 | O | LEU | B | 706 | 27.984 | 67.154 | 81.920 | 1.00 | 23.98 | B | O |
| ATOM | 4868 | N | GLU | B | 707 | 28.309 | 69.177 | 82.850 | 1.00 | 25.30 | B | N |
| ATOM | 4869 | CA | GLU | B | 707 | 27.216 | 69.034 | 83.808 | 1.00 | 25.69 | B | C |
| ATOM | 4870 | CB | GLU | B | 707 | 27.469 | 69.932 | 85.021 | 1.00 | 29.45 | B | C |
| ATOM | 4871 | CG | GLU | B | 707 | 28.619 | 69.469 | 85.899 | 1.00 | 34.15 | B | C |
| ATOM | 4872 | CD | GLU | B | 707 | 28.454 | 68.031 | 86.345 | 1.00 | 37.08 | B | C |
| ATOM | 4873 | OE1 | GLU | B | 707 | 29.369 | 67.217 | 86.096 | 1.00 | 39.76 | B | O |
| ATOM | 4874 | OE2 | GLU | B | 707 | 27.403 | 67.711 | 86.941 | 1.00 | 40.46 | B | O |
| ATOM | 4875 | C | GLU | B | 707 | 25.884 | 69.410 | 83.162 | 1.00 | 24.34 | B | C |
| ATOM | 4876 | O | GLU | B | 707 | 25.768 | 70.454 | 82.530 | 1.00 | 23.42 | B | O |
| ATOM | 4877 | N | GLU | B | 708 | 24.877 | 68.563 | 83.339 | 1.00 | 23.47 | B | N |
| ATOM | 4878 | CA | GLU | B | 708 | 23.557 | 68.805 | 82.761 | 1.00 | 25.19 | B | C |
| ATOM | 4879 | CB | GLU | B | 708 | 22.787 | 67.483 | 82.656 | 1.00 | 27.44 | B | C |
| ATOM | 4880 | CG | GLU | B | 708 | 23.685 | 66.255 | 82.712 | 1.00 | 32.20 | B | C |
| ATOM | 4881 | CD | GLU | B | 708 | 23.269 | 65.163 | 81.745 | 1.00 | 32.38 | B | C |
| ATOM | 4882 | OE1 | GLU | B | 708 | 22.068 | 64.854 | 81.680 | 1.00 | 32.46 | B | O |
| ATOM | 4883 | OE2 | GLU | B | 708 | 24.148 | 64.605 | 81.054 | 1.00 | 35.74 | B | O |
| ATOM | 4884 | C | GLU | B | 708 | 22.718 | 69.836 | 83.525 | 1.00 | 23.69 | B | C |
| ATOM | 4885 | O | GLU | B | 708 | 22.837 | 69.974 | 84.739 | 1.00 | 24.10 | B | O |
| ATOM | 4886 | N | GLY | B | 709 | 21.871 | 70.561 | 82.795 | 1.00 | 21.52 | B | N |
| ATOM | 4887 | CA | GLY | B | 709 | 21.023 | 71.566 | 83.408 | 1.00 | 18.80 | B | C |
| ATOM | 4888 | C | GLY | B | 709 | 21.698 | 72.918 | 83.510 | 1.00 | 19.01 | B | C |
| ATOM | 4889 | O | GLY | B | 709 | 22.820 | 73.091 | 83.032 | 1.00 | 19.55 | B | O |
| ATOM | 4890 | N | PRO | B | 710 | 21.039 | 73.905 | 84.133 | 1.00 | 18.24 | B | N |
| ATOM | 4891 | CD | PRO | B | 710 | 19.690 | 73.784 | 84.713 | 1.00 | 18.42 | B | C |
| ATOM | 4892 | CA | PRO | B | 710 | 21.583 | 75.258 | 84.297 | 1.00 | 18.33 | B | C |
| ATOM | 4893 | CB | PRO | B | 710 | 20.552 | 75.956 | 85.184 | 1.00 | 17.32 | B | C |
| ATOM | 4894 | CG | PRO | B | 710 | 19.288 | 75.214 | 84.940 | 1.00 | 16.80 | B | C |
| ATOM | 4895 | C | PRO | B | 710 | 22.983 | 75.332 | 84.902 | 1.00 | 19.92 | B | C |
| ATOM | 4896 | O | PRO | B | 710 | 23.743 | 76.259 | 84.617 | 1.00 | 20.94 | B | O |
| ATOM | 4897 | N | ILE | B | 711 | 23.322 | 74.360 | 85.740 | 1.00 | 19.48 | B | N |
| ATOM | 4898 | CA | ILE | B | 711 | 24.618 | 74.350 | 86.398 | 1.00 | 19.81 | B | C |
| ATOM | 4899 | CB | ILE | B | 711 | 24.687 | 73.208 | 87.446 | 1.00 | 19.55 | B | C |
| ATOM | 4900 | CG2 | ILE | B | 711 | 25.035 | 71.890 | 86.780 | 1.00 | 20.96 | B | C |
| ATOM | 4901 | CG1 | ILE | B | 711 | 25.724 | 73.550 | 88.517 | 1.00 | 22.03 | B | C |
| ATOM | 4902 | CD1 | ILE | B | 711 | 25.503 | 74.897 | 89.185 | 1.00 | 21.10 | B | C |
| ATOM | 4903 | C | ILE | B | 711 | 25.777 | 74.228 | 85.415 | 1.00 | 20.26 | B | C |
| ATOM | 4904 | O | ILE | B | 711 | 26.876 | 74.725 | 85.673 | 1.00 | 20.86 | B | O |
| ATOM | 4905 | N | GLY | B | 712 | 25.525 | 73.580 | 84.282 | 1.00 | 18.83 | B | N |
| ATOM | 4906 | CA | GLY | B | 712 | 26.567 | 73.410 | 83.291 | 1.00 | 20.31 | B | C |
| ATOM | 4907 | C | GLY | B | 712 | 26.686 | 74.539 | 82.280 | 1.00 | 20.25 | B | C |
| ATOM | 4908 | O | GLY | B | 712 | 27.568 | 74.505 | 81.431 | 1.00 | 20.41 | B | O |
| ATOM | 4909 | N | ASN | B | 713 | 25.817 | 75.544 | 82.365 | 1.00 | 19.94 | B | N |
| ATOM | 4910 | CA | ASN | B | 713 | 25.860 | 76.654 | 81.416 | 1.00 | 18.93 | B | C |
| ATOM | 4911 | CB | ASN | B | 713 | 24.452 | 76.956 | 80.881 | 1.00 | 16.93 | B | C |
| ATOM | 4912 | CG | ASN | B | 713 | 24.439 | 78.108 | 79.879 | 1.00 | 17.45 | B | C |
| ATOM | 4913 | OD1 | ASN | B | 713 | 23.672 | 79.070 | 80.015 | 1.00 | 16.35 | B | O |
| ATOM | 4914 | ND2 | ASN | B | 713 | 25.292 | 78.015 | 78.865 | 1.00 | 14.86 | B | N |
| ATOM | 4915 | C | ASN | B | 713 | 26.454 | 77.939 | 81.970 | 1.00 | 19.73 | B | C |
| ATOM | 4916 | O | ASN | B | 713 | 26.044 | 78.420 | 83.024 | 1.00 | 20.37 | B | O |
| ATOM | 4917 | N | ASP | B | 714 | 27.416 | 78.491 | 81.237 | 1.00 | 19.34 | B | N |
| ATOM | 4918 | CA | ASP | B | 714 | 28.065 | 79.746 | 81.592 | 1.00 | 18.48 | B | C |
| ATOM | 4919 | CB | ASP | B | 714 | 29.587 | 79.576 | 81.593 | 1.00 | 19.20 | B | C |
| ATOM | 4920 | CG | ASP | B | 714 | 30.318 | 80.815 | 82.090 | 1.00 | 20.83 | B | C |
| ATOM | 4921 | OD1 | ASP | B | 714 | 29.688 | 81.894 | 82.197 | 1.00 | 21.69 | B | O |
| ATOM | 4922 | OD2 | ASP | B | 714 | 31.530 | 80.705 | 82.374 | 1.00 | 21.28 | B | O |
| ATOM | 4923 | C | ASP | B | 714 | 27.647 | 80.735 | 80.503 | 1.00 | 19.18 | B | C |
| ATOM | 4924 | O | ASP | B | 714 | 28.282 | 80.811 | 79.449 | 1.00 | 18.79 | B | O |
| ATOM | 4925 | N | ILE | B | 715 | 26.576 | 81.480 | 80.765 | 1.00 | 17.05 | B | N |
| ATOM | 4926 | CA | ILE | B | 715 | 26.038 | 82.442 | 79.815 | 1.00 | 17.43 | B | C |
| ATOM | 4927 | CB | ILE | B | 715 | 24.824 | 83.198 | 80.414 | 1.00 | 18.26 | B | C |
| ATOM | 4928 | CG2 | ILE | B | 715 | 25.297 | 84.224 | 81.432 | 1.00 | 18.30 | B | C |
| ATOM | 4929 | CG1 | ILE | B | 715 | 24.024 | 83.880 | 79.304 | 1.00 | 16.63 | B | C |
| ATOM | 4930 | CD1 | ILE | B | 715 | 22.826 | 84.654 | 79.811 | 1.00 | 13.91 | B | C |
| ATOM | 4931 | C | ILE | B | 715 | 27.067 | 83.451 | 79.343 | 1.00 | 18.65 | B | C |
| ATOM | 4932 | O | ILE | B | 715 | 26.942 | 84.004 | 78.252 | 1.00 | 19.56 | B | O |
| ATOM | 4933 | N | ARG | B | 716 | 28.083 | 83.697 | 80.160 | 1.00 | 19.49 | B | N |
| ATOM | 4934 | CA | ARG | B | 716 | 29.117 | 84.648 | 79.781 | 1.00 | 22.86 | B | C |
| ATOM | 4935 | CB | ARG | B | 716 | 30.104 | 84.843 | 80.932 | 1.00 | 26.46 | B | C |
| ATOM | 4936 | CG | ARG | B | 716 | 29.653 | 85.849 | 81.983 | 1.00 | 32.60 | B | C |
| ATOM | 4937 | CD | ARG | B | 716 | 30.619 | 85.904 | 83.160 | 1.00 | 35.35 | B | C |
| ATOM | 4938 | NE | ARG | B | 716 | 31.017 | 84.571 | 83.612 | 1.00 | 40.45 | B | N |
| ATOM | 4939 | CZ | ARG | B | 716 | 32.020 | 84.330 | 84.455 | 1.00 | 42.12 | B | C |
| ATOM | 4940 | NH1 | ARG | B | 716 | 32.738 | 85.333 | 84.945 | 1.00 | 42.93 | B | N |
| ATOM | 4941 | NH2 | ARG | B | 716 | 32.304 | 83.085 | 84.814 | 1.00 | 42.34 | B | N |
| ATOM | 4942 | C | ARG | B | 716 | 29.862 | 84.133 | 78.548 | 1.00 | 23.94 | B | C |
| ATOM | 4943 | O | ARG | B | 716 | 30.459 | 84.909 | 77.795 | 1.00 | 24.03 | B | O |
| ATOM | 4944 | N | LYS | B | 717 | 29.809 | 82.819 | 78.344 | 1.00 | 22.93 | B | N |
| ATOM | 4945 | CA | LYS | B | 717 | 30.486 | 82.182 | 77.222 | 1.00 | 22.59 | B | C |
| ATOM | 4946 | CB | LYS | B | 717 | 31.281 | 80.974 | 77.725 | 1.00 | 22.91 | B | C |
| ATOM | 4947 | CG | LYS | B | 717 | 32.750 | 81.263 | 77.952 | 1.00 | 25.22 | B | C |
| ATOM | 4948 | CD | LYS | B | 717 | 33.286 | 80.476 | 79.125 | 1.00 | 27.98 | B | C |
| ATOM | 4949 | CE | LYS | B | 717 | 34.767 | 80.767 | 79.348 | 1.00 | 30.59 | B | C |
| ATOM | 4950 | NZ | LYS | B | 717 | 35.502 | 79.566 | 79.868 | 1.00 | 34.13 | B | N |
| ATOM | 4951 | C | LYS | B | 717 | 29.560 | 81.731 | 76.095 | 1.00 | 20.65 | B | C |
| ATOM | 4952 | O | LYS | B | 717 | 29.944 | 81.752 | 74.927 | 1.00 | 21.08 | B | O |
| ATOM | 4953 | N | THR | B | 718 | 28.343 | 81.339 | 76.446 | 1.00 | 18.68 | B | N |
| ATOM | 4954 | CA | THR | B | 718 | 27.384 | 80.832 | 75.469 | 1.00 | 17.76 | B | C |
| ATOM | 4955 | CB | THR | B | 718 | 26.722 | 79.549 | 75.993 | 1.00 | 16.68 | B | C |
| ATOM | 4956 | OG1 | THR | B | 718 | 25.818 | 79.889 | 77.053 | 1.00 | 17.65 | B | O |
| ATOM | 4957 | CG2 | THR | B | 718 | 27.771 | 78.574 | 76.513 | 1.00 | 14.72 | B | C |
| ATOM | 4958 | C | THR | B | 718 | 26.254 | 81.769 | 75.043 | 1.00 | 16.91 | B | C |
| ATOM | 4959 | O | THR | B | 718 | 25.637 | 81.550 | 74.007 | 1.00 | 16.87 | B | O |
| ATOM | 4960 | N | ASN | B | 719 | 25.976 | 82.799 | 75.831 | 1.00 | 16.52 | B | N |
| ATOM | 4961 | CA | ASN | B | 719 | 24.882 | 83.722 | 75.527 | 1.00 | 15.85 | B | C |
| ATOM | 4962 | CB | ASN | B | 719 | 25.137 | 84.477 | 74.220 | 1.00 | 16.58 | B | C |
| ATOM | 4963 | CG | ASN | B | 719 | 24.367 | 85.789 | 74.143 | 1.00 | 18.50 | B | C |
| ATOM | 4964 | OD1 | ASN | B | 719 | 24.479 | 86.647 | 75.018 | 1.00 | 21.63 | B | O |
| ATOM | 4965 | ND2 | ASN | B | 719 | 23.580 | 85.950 | 73.088 | 1.00 | 21.02 | B | N |
| ATOM | 4966 | C | ASN | B | 719 | 23.531 | 83.000 | 75.449 | 1.00 | 15.51 | B | C |
| ATOM | 4967 | O | ASN | B | 719 | 22.626 | 83.418 | 74.719 | 1.00 | 14.73 | B | O |
| ATOM | 4968 | N | VAL | B | 720 | 23.412 | 81.902 | 76.193 | 1.00 | 14.57 | B | N |
| ATOM | 4969 | CA | VAL | B | 720 | 22.177 | 81.132 | 76.268 | 1.00 | 11.62 | B | C |
| ATOM | 4970 | CB | VAL | B | 720 | 22.440 | 79.604 | 76.201 | 1.00 | 14.14 | B | C |
| ATOM | 4971 | CG1 | VAL | B | 720 | 21.170 | 78.844 | 76.581 | 1.00 | 12.47 | B | C |
| ATOM | 4972 | CG2 | VAL | B | 720 | 22.892 | 79.195 | 74.793 | 1.00 | 10.90 | B | C |
| ATOM | 4973 | C | VAL | B | 720 | 21.569 | 81.464 | 77.636 | 1.00 | 13.42 | B | C |
| ATOM | 4974 | O | VAL | B | 720 | 22.246 | 81.372 | 78.664 | 1.00 | 13.90 | B | O |
| ATOM | 4975 | N | ALA | B | 721 | 20.298 | 81.848 | 77.645 | 1.00 | 12.59 | B | N |
| ATOM | 4976 | CA | ALA | B | 721 | 19.600 | 82.216 | 78.876 | 1.00 | 12.91 | B | C |
| ATOM | 4977 | CB | ALA | B | 721 | 18.221 | 82.760 | 78.536 | 1.00 | 12.04 | B | C |
| ATOM | 4978 | C | ALA | B | 721 | 19.466 | 81.065 | 79.864 | 1.00 | 12.52 | B | C |
| ATOM | 4979 | O | ALA | B | 721 | 19.246 | 79.927 | 79.473 | 1.00 | 12.55 | B | O |
| ATOM | 4980 | N | GLN | B | 722 | 19.591 | 81.370 | 81.151 | 1.00 | 14.80 | B | N |
| ATOM | 4981 | CA | GLN | B | 722 | 19.465 | 80.347 | 82.185 | 1.00 | 14.41 | B | C |
| ATOM | 4982 | CB | GLN | B | 722 | 19.976 | 80.878 | 83.528 | 1.00 | 14.63 | B | C |
| ATOM | 4983 | CG | GLN | B | 722 | 21.496 | 80.859 | 83.661 | 1.00 | 15.32 | B | C |
| ATOM | 4984 | CD | GLN | B | 722 | 22.084 | 79.454 | 83.587 | 1.00 | 19.34 | B | C |
| ATOM | 4985 | OE1 | GLN | B | 722 | 22.739 | 78.981 | 84.522 | 1.00 | 19.73 | B | O |
| ATOM | 4986 | NE2 | GLN | B | 722 | 21.854 | 78.782 | 82.470 | 1.00 | 20.05 | B | N |
| ATOM | 4987 | C | GLN | B | 722 | 18.000 | 79.929 | 82.284 | 1.00 | 14.71 | B | C |
| ATOM | 4988 | O | GLN | B | 722 | 17.681 | 78.822 | 82.733 | 1.00 | 14.99 | B | O |
| ATOM | 4989 | N | ILE | B | 723 | 17.110 | 80.824 | 81.857 | 1.00 | 14.47 | B | N |
| ATOM | 4990 | CA | ILE | B | 723 | 15.681 | 80.534 | 81.852 | 1.00 | 15.80 | B | C |
| ATOM | 4991 | CB | ILE | B | 723 | 14.874 | 81.760 | 81.367 | 1.00 | 14.07 | B | C |
| ATOM | 4992 | CG2 | ILE | B | 723 | 13.468 | 81.343 | 80.967 | 1.00 | 13.11 | B | C |
| ATOM | 4993 | CG1 | ILE | B | 723 | 14.818 | 82.805 | 82.483 | 1.00 | 16.69 | B | C |
| ATOM | 4994 | CD1 | ILE | B | 723 | 14.133 | 84.103 | 82.096 | 1.00 | 13.69 | B | C |
| ATOM | 4995 | C | ILE | B | 723 | 15.449 | 79.362 | 80.885 | 1.00 | 16.84 | B | C |
| ATOM | 4996 | O | ILE | B | 723 | 14.672 | 78.438 | 81.161 | 1.00 | 18.42 | B | O |
| ATOM | 4997 | N | ARG | B | 724 | 16.142 | 79.411 | 79.751 | 1.00 | 16.19 | B | N |
| ATOM | 4998 | CA | ARG | B | 724 | 16.041 | 78.377 | 78.725 | 1.00 | 14.80 | B | C |
| ATOM | 4999 | CB | ARG | B | 724 | 16.796 | 78.834 | 77.456 | 1.00 | 14.44 | B | C |
| ATOM | 5000 | CG | ARG | B | 724 | 16.773 | 77.848 | 76.278 | 1.00 | 12.78 | B | C |
| ATOM | 5001 | CD | ARG | B | 724 | 15.363 | 77.474 | 75.854 | 1.00 | 10.98 | B | C |
| ATOM | 5002 | NE | ARG | B | 724 | 14.623 | 78.617 | 75.329 | 1.00 | 14.92 | B | N |
| ATOM | 5003 | CZ | ARG | B | 724 | 14.634 | 79.002 | 74.053 | 1.00 | 16.27 | B | C |
| ATOM | 5004 | NH1 | ARG | B | 724 | 15.350 | 78.335 | 73.156 | 1.00 | 15.79 | B | N |
| ATOM | 5005 | NH2 | ARG | B | 724 | 13.931 | 80.060 | 73.672 | 1.00 | 14.64 | B | N |
| ATOM | 5006 | C | ARG | B | 724 | 16.635 | 77.080 | 79.265 | 1.00 | 12.44 | B | C |
| ATOM | 5007 | O | ARG | B | 724 | 16.033 | 76.015 | 79.148 | 1.00 | 12.58 | B | O |
| ATOM | 5008 | N | MET | B | 725 | 17.816 | 77.175 | 79.865 | 1.00 | 10.67 | B | N |
| ATOM | 5009 | CA | MET | B | 725 | 18.470 | 75.995 | 80.418 | 1.00 | 11.85 | B | C |
| ATOM | 5010 | CB | MET | B | 725 | 19.795 | 76.386 | 81.072 | 1.00 | 10.57 | B | C |
| ATOM | 5011 | CG | MET | B | 725 | 20.864 | 76.848 | 80.095 | 1.00 | 10.67 | B | C |
| ATOM | 5012 | SD | MET | B | 725 | 21.369 | 75.564 | 78.929 | 1.00 | 14.85 | B | S |
| ATOM | 5013 | CE | MET | B | 725 | 21.925 | 74.248 | 80.010 | 1.00 | 10.05 | B | C |
| ATOM | 5014 | C | MET | B | 725 | 17.572 | 75.296 | 81.446 | 1.00 | 13.88 | B | C |
| ATOM | 5015 | O | MET | B | 725 | 17.411 | 74.073 | 81.412 | 1.00 | 15.02 | B | O |
| ATOM | 5016 | N | ALA | B | 726 | 16.983 | 76.080 | 82.349 | 1.00 | 14.89 | B | N |
| ATOM | 5017 | CA | ALA | B | 726 | 16.109 | 75.546 | 83.389 | 1.00 | 13.48 | B | C |
| ATOM | 5018 | CB | ALA | B | 726 | 15.725 | 76.652 | 84.373 | 1.00 | 9.01 | B | C |
| ATOM | 5019 | C | ALA | B | 726 | 14.861 | 74.930 | 82.781 | 1.00 | 13.73 | B | C |
| ATOM | 5020 | O | ALA | B | 726 | 14.420 | 73.856 | 83.207 | 1.00 | 14.26 | B | O |
| ATOM | 5021 | N | TYR | B | 727 | 14.286 | 75.612 | 81.790 | 1.00 | 12.73 | B | N |
| ATOM | 5022 | CA | TYR | B | 727 | 13.089 | 75.105 | 81.131 | 1.00 | 10.61 | B | C |
| ATOM | 5023 | CB | TYR | B | 727 | 12.628 | 76.059 | 80.016 | 1.00 | 11.73 | B | C |
| ATOM | 5024 | CG | TYR | B | 727 | 11.520 | 75.468 | 79.179 | 1.00 | 10.47 | B | C |
| ATOM | 5025 | CD1 | TYR | B | 727 | 11.801 | 74.789 | 77.997 | 1.00 | 13.48 | B | C |
| ATOM | 5026 | CE1 | TYR | B | 727 | 10.784 | 74.181 | 77.253 | 1.00 | 12.31 | B | C |
| ATOM | 5027 | CD2 | TYR | B | 727 | 10.195 | 75.530 | 79.598 | 1.00 | 11.54 | B | C |
| ATOM | 5028 | CE2 | TYR | B | 727 | 9.170 | 74.926 | 78.862 | 1.00 | 11.41 | B | C |
| ATOM | 5029 | CZ | TYR | B | 727 | 9.474 | 74.255 | 77.693 | 1.00 | 11.44 | B | C |
| ATOM | 5030 | OH | TYR | B | 727 | 8.465 | 73.673 | 76.961 | 1.00 | 13.12 | B | O |
| ATOM | 5031 | C | TYR | B | 727 | 13.320 | 73.716 | 80.544 | 1.00 | 9.91 | B | C |
| ATOM | 5032 | O | TYR | B | 727 | 12.549 | 72.797 | 80.800 | 1.00 | 10.26 | B | O |
| ATOM | 5033 | N | ARG | B | 728 | 14.381 | 73.564 | 79.756 | 1.00 | 11.78 | B | N |
| ATOM | 5034 | CA | ARG | B | 728 | 14.692 | 72.275 | 79.127 | 1.00 | 11.02 | B | C |
| ATOM | 5035 | CB | ARG | B | 728 | 15.945 | 72.384 | 78.250 | 1.00 | 9.88 | B | C |
| ATOM | 5036 | CG | ARG | B | 728 | 15.844 | 73.397 | 77.120 | 1.00 | 14.65 | B | C |
| ATOM | 5037 | CD | ARG | B | 728 | 14.888 | 72.939 | 76.021 | 1.00 | 13.10 | B | C |
| ATOM | 5038 | NE | ARG | B | 728 | 14.976 | 73.812 | 74.853 | 1.00 | 14.33 | B | N |
| ATOM | 5039 | CZ | ARG | B | 728 | 14.127 | 73.786 | 73.832 | 1.00 | 11.86 | B | C |
| ATOM | 5040 | NH1 | ARG | B | 728 | 13.119 | 72.926 | 73.828 | 1.00 | 9.38 | B | N |
| ATOM | 5041 | NH2 | ARG | B | 728 | 14.283 | 74.632 | 72.822 | 1.00 | 10.33 | B | N |
| ATOM | 5042 | C | ARG | B | 728 | 14.933 | 71.186 | 80.155 | 1.00 | 11.57 | B | C |
| ATOM | 5043 | O | ARG | B | 728 | 14.396 | 70.080 | 80.055 | 1.00 | 11.54 | B | O |
| ATOM | 5044 | N | TYR | B | 729 | 15.768 | 71.503 | 81.135 | 1.00 | 12.65 | B | N |
| ATOM | 5045 | CA | TYR | B | 729 | 16.104 | 70.549 | 82.176 | 1.00 | 12.68 | B | C |
| ATOM | 5046 | CB | TYR | B | 729 | 17.048 | 71.205 | 83.174 | 1.00 | 14.97 | B | C |
| ATOM | 5047 | CG | TYR | B | 729 | 17.672 | 70.226 | 84.132 | 1.00 | 20.67 | B | C |
| ATOM | 5048 | CD1 | TYR | B | 729 | 18.217 | 69.023 | 83.678 | 1.00 | 19.51 | B | C |
| ATOM | 5049 | CE1 | TYR | B | 729 | 18.779 | 68.116 | 84.564 | 1.00 | 22.60 | B | C |
| ATOM | 5050 | CD2 | TYR | B | 729 | 17.708 | 70.498 | 85.502 | 1.00 | 22.34 | B | C |
| ATOM | 5051 | CE2 | TYR | B | 729 | 18.266 | 69.601 | 86.396 | 1.00 | 23.54 | B | C |
| ATOM | 5052 | CZ | TYR | B | 729 | 18.800 | 68.412 | 85.926 | 1.00 | 25.39 | B | C |
| ATOM | 5053 | OH | TYR | B | 729 | 19.343 | 67.523 | 86.828 | 1.00 | 28.60 | B | O |
| ATOM | 5054 | C | TYR | B | 729 | 14.865 | 70.026 | 82.884 | 1.00 | 12.18 | B | C |
| ATOM | 5055 | O | TYR | B | 729 | 14.668 | 68.814 | 83.015 | 1.00 | 13.21 | B | O |
| ATOM | 5056 | N | GLU | B | 730 | 14.012 | 70.945 | 83.314 | 1.00 | 12.14 | B | N |
| ATOM | 5057 | CA | GLU | B | 730 | 12.795 | 70.577 | 84.017 | 1.00 | 13.77 | B | C |
| ATOM | 5058 | CB | GLU | B | 730 | 12.090 | 71.836 | 84.530 | 1.00 | 14.61 | B | C |
| ATOM | 5059 | CG | GLU | B | 730 | 12.932 | 72.664 | 85.477 | 1.00 | 15.79 | B | C |
| ATOM | 5060 | CD | GLU | B | 730 | 12.300 | 74.002 | 85.800 | 1.00 | 20.19 | B | C |
| ATOM | 5061 | OE1 | GLU | B | 730 | 12.963 | 74.834 | 86.463 | 1.00 | 21.17 | B | O |
| ATOM | 5062 | OE2 | GLU | B | 730 | 11.139 | 74.224 | 85.395 | 1.00 | 21.23 | B | O |
| ATOM | 5063 | C | GLU | B | 730 | 11.827 | 69.749 | 83.179 | 1.00 | 15.17 | B | C |
| ATOM | 5064 | O | GLU | B | 730 | 11.291 | 68.750 | 83.669 | 1.00 | 16.83 | B | O |
| ATOM | 5065 | N | THR | B | 731 | 11.590 | 70.137 | 81.924 | 1.00 | 14.59 | B | N |
| ATOM | 5066 | CA | THR | B | 731 | 10.654 | 69.352 | 81.121 | 1.00 | 13.75 | B | C |
| ATOM | 5067 | CB | THR | B | 731 | 10.133 | 70.150 | 79.885 | 1.00 | 15.60 | B | C |
| ATOM | 5068 | OG1 | THR | B | 731 | 10.677 | 69.608 | 78.681 | 1.00 | 19.47 | B | O |
| ATOM | 5069 | CG2 | THR | B | 731 | 10.483 | 71.604 | 79.999 | 1.00 | 8.84 | B | C |
| ATOM | 5070 | C | THR | B | 731 | 11.240 | 67.990 | 80.716 | 1.00 | 12.34 | B | C |
| ATOM | 5071 | O | THR | B | 731 | 10.505 | 67.013 | 80.555 | 1.00 | 12.59 | B | O |
| ATOM | 5072 | N | TRP | B | 732 | 12.563 | 67.910 | 80.590 | 1.00 | 11.08 | B | N |
| ATOM | 5073 | CA | TRP | B | 732 | 13.212 | 66.637 | 80.255 | 1.00 | 10.63 | B | C |
| ATOM | 5074 | CB | TRP | B | 732 | 14.689 | 66.867 | 79.939 | 1.00 | 7.51 | B | C |
| ATOM | 5075 | CG | TRP | B | 732 | 15.482 | 65.624 | 79.616 | 1.00 | 8.17 | B | C |
| ATOM | 5076 | CD2 | TRP | B | 732 | 16.904 | 65.458 | 79.748 | 1.00 | 7.03 | B | C |
| ATOM | 5077 | CE2 | TRP | B | 732 | 17.224 | 64.170 | 79.263 | 1.00 | 6.78 | B | C |
| ATOM | 5078 | CE3 | TRP | B | 732 | 17.939 | 66.276 | 80.229 | 1.00 | 8.62 | B | C |
| ATOM | 5079 | CD1 | TRP | B | 732 | 15.011 | 64.451 | 79.075 | 1.00 | 7.54 | B | C |
| ATOM | 5080 | NE1 | TRP | B | 732 | 16.055 | 63.576 | 78.859 | 1.00 | 4.81 | B | N |
| ATOM | 5081 | CZ2 | TRP | B | 732 | 18.538 | 63.683 | 79.244 | 1.00 | 6.74 | B | C |
| ATOM | 5082 | CZ3 | TRP | B | 732 | 19.247 | 65.788 | 80.207 | 1.00 | 7.46 | B | C |
| ATOM | 5083 | CH2 | TRP | B | 732 | 19.530 | 64.504 | 79.717 | 1.00 | 6.76 | B | C |
| ATOM | 5084 | C | TRP | B | 732 | 13.077 | 65.706 | 81.466 | 1.00 | 12.44 | B | C |
| ATOM | 5085 | O | TRP | B | 732 | 12.713 | 64.531 | 81.334 | 1.00 | 12.32 | B | O |
| ATOM | 5086 | N | CYS | B | 733 | 13.368 | 66.239 | 82.650 | 1.00 | 14.42 | B | N |
| ATOM | 5087 | CA | CYS | B | 733 | 13.259 | 65.453 | 83.886 | 1.00 | 16.33 | B | C |
| ATOM | 5088 | CB | CYS | B | 733 | 13.680 | 66.300 | 85.093 | 1.00 | 13.63 | B | C |
| ATOM | 5089 | SG | CYS | B | 733 | 15.467 | 66.386 | 85.338 | 1.00 | 19.07 | B | S |
| ATOM | 5090 | C | CYS | B | 733 | 11.822 | 64.964 | 84.084 | 1.00 | 14.59 | B | C |
| ATOM | 5091 | O | CYS | B | 733 | 11.582 | 63.807 | 84.450 | 1.00 | 14.04 | B | O |
| ATOM | 5092 | N | TYR | B | 734 | 10.869 | 65.853 | 83.826 | 1.00 | 13.43 | B | N |
| ATOM | 5093 | CA | TYR | B | 734 | 9.465 | 65.524 | 83.977 | 1.00 | 13.87 | B | C |
| ATOM | 5094 | CB | TYR | B | 734 | 8.620 | 66.743 | 83.624 | 1.00 | 15.41 | B | C |
| ATOM | 5095 | CG | TYR | B | 734 | 7.164 | 66.606 | 83.983 | 1.00 | 19.24 | B | C |
| ATOM | 5096 | CD1 | TYR | B | 734 | 6.669 | 67.107 | 85.188 | 1.00 | 22.20 | B | C |
| ATOM | 5097 | CE1 | TYR | B | 734 | 5.316 | 66.999 | 85.516 | 1.00 | 22.69 | B | C |
| ATOM | 5098 | CD2 | TYR | B | 734 | 6.274 | 65.990 | 83.115 | 1.00 | 21.58 | B | C |
| ATOM | 5099 | CE2 | TYR | B | 734 | 4.922 | 65.876 | 83.431 | 1.00 | 24.91 | B | C |
| ATOM | 5100 | CZ | TYR | B | 734 | 4.448 | 66.386 | 84.631 | 1.00 | 24.18 | B | C |
| ATOM | 5101 | OH | TYR | B | 734 | 3.102 | 66.303 | 84.916 | 1.00 | 25.22 | B | O |
| ATOM | 5102 | C | TYR | B | 734 | 9.035 | 64.328 | 83.125 | 1.00 | 14.44 | B | C |
| ATOM | 5103 | O | TYR | B | 734 | 8.277 | 63.473 | 83.579 | 1.00 | 13.97 | B | O |
| ATOM | 5104 | N | GLU | B | 735 | 9.517 | 64.264 | 81.890 | 1.00 | 15.28 | B | N |
| ATOM | 5105 | CA | GLU | B | 735 | 9.149 | 63.161 | 81.005 | 1.00 | 15.67 | B | C |
| ATOM | 5106 | CB | GLU | B | 735 | 9.598 | 63.460 | 79.566 | 1.00 | 16.67 | B | C |
| ATOM | 5107 | CG | GLU | B | 735 | 8.866 | 64.644 | 78.923 | 1.00 | 16.48 | B | C |
| ATOM | 5108 | CD | GLU | B | 735 | 7.357 | 64.446 | 78.855 | 1.00 | 13.61 | B | C |
| ATOM | 5109 | OE1 | GLU | B | 735 | 6.901 | 63.382 | 78.394 | 1.00 | 12.69 | B | O |
| ATOM | 5110 | OE2 | GLU | B | 735 | 6.618 | 65.365 | 79.264 | 1.00 | 17.36 | B | O |
| ATOM | 5111 | C | GLU | B | 735 | 9.755 | 61.845 | 81.485 | 1.00 | 14.41 | B | C |
| ATOM | 5112 | O | GLU | B | 735 | 9.115 | 60.796 | 81.428 | 1.00 | 11.84 | B | O |
| ATOM | 5113 | N | LEU | B | 736 | 10.994 | 61.901 | 81.956 | 1.00 | 14.19 | B | N |
| ATOM | 5114 | CA | LEU | B | 736 | 11.656 | 60.698 | 82.456 | 1.00 | 16.22 | B | C |
| ATOM | 5115 | CB | LEU | B | 736 | 13.122 | 61.000 | 82.765 | 1.00 | 15.55 | B | C |
| ATOM | 5116 | CG | LEU | B | 736 | 14.039 | 61.205 | 81.551 | 1.00 | 17.54 | B | C |
| ATOM | 5117 | CD1 | LEU | B | 736 | 15.339 | 61.863 | 82.007 | 1.00 | 16.42 | B | C |
| ATOM | 5118 | CD2 | LEU | B | 736 | 14.315 | 59.863 | 80.859 | 1.00 | 14.16 | B | C |
| ATOM | 5119 | C | LEU | B | 736 | 10.948 | 60.191 | 83.719 | 1.00 | 16.60 | B | C |
| ATOM | 5120 | O | LEU | B | 736 | 10.747 | 58.994 | 83.901 | 1.00 | 15.33 | B | O |
| ATOM | 5121 | N | ASN | B | 737 | 10.564 | 61.121 | 84.586 | 1.00 | 18.95 | B | N |
| ATOM | 5122 | CA | ASN | B | 737 | 9.880 | 60.780 | 85.826 | 1.00 | 19.99 | B | C |
| ATOM | 5123 | CB | ASN | B | 737 | 9.636 | 62.040 | 86.651 | 1.00 | 21.42 | B | C |
| ATOM | 5124 | CG | ASN | B | 737 | 9.162 | 61.724 | 88.049 | 1.00 | 23.10 | B | C |
| ATOM | 5125 | OD1 | ASN | B | 737 | 9.896 | 61.137 | 88.834 | 1.00 | 27.32 | B | O |
| ATOM | 5126 | ND2 | ASN | B | 737 | 7.929 | 62.107 | 88.367 | 1.00 | 24.07 | B | N |
| ATOM | 5127 | C | ASN | B | 737 | 8.553 | 60.066 | 85.596 | 1.00 | 20.48 | B | C |
| ATOM | 5128 | O | ASN | B | 737 | 8.180 | 59.167 | 86.359 | 1.00 | 20.38 | B | O |
| ATOM | 5129 | N | LEU | B | 738 | 7.841 | 60.468 | 84.548 | 1.00 | 19.04 | B | N |
| ATOM | 5130 | CA | LEU | B | 738 | 6.556 | 59.858 | 84.230 | 1.00 | 19.24 | B | C |
| ATOM | 5131 | CB | LEU | B | 738 | 5.976 | 60.467 | 82.949 | 1.00 | 16.61 | B | C |
| ATOM | 5132 | CG | LEU | B | 738 | 5.340 | 61.855 | 83.082 | 1.00 | 16.71 | B | C |
| ATOM | 5133 | CD1 | LEU | B | 738 | 4.967 | 62.385 | 81.707 | 1.00 | 16.97 | B | C |
| ATOM | 5134 | CD2 | LEU | B | 738 | 4.111 | 61.771 | 83.958 | 1.00 | 15.74 | B | C |
| ATOM | 5135 | C | LEU | B | 738 | 6.696 | 58.349 | 84.065 | 1.00 | 19.34 | B | C |
| ATOM | 5136 | O | LEU | B | 738 | 5.817 | 57.586 | 84.456 | 1.00 | 18.17 | B | O |
| ATOM | 5137 | N | ILE | B | 739 | 7.810 | 57.923 | 83.486 | 1.00 | 20.16 | B | N |
| ATOM | 5138 | CA | ILE | B | 739 | 8.050 | 56.505 | 83.266 | 1.00 | 20.40 | B | C |
| ATOM | 5139 | CB | ILE | B | 739 | 9.235 | 56.275 | 82.303 | 1.00 | 19.20 | B | C |
| ATOM | 5140 | CG2 | ILE | B | 739 | 9.609 | 54.792 | 82.278 | 1.00 | 15.28 | B | C |
| ATOM | 5141 | CG1 | ILE | B | 739 | 8.858 | 56.757 | 80.895 | 1.00 | 21.30 | B | C |
| ATOM | 5142 | CD1 | ILE | B | 739 | 10.007 | 57.380 | 80.121 | 1.00 | 21.80 | B | C |
| ATOM | 5143 | C | ILE | B | 739 | 8.348 | 55.816 | 84.584 | 1.00 | 20.85 | B | C |
| ATOM | 5144 | O | ILE | B | 739 | 7.847 | 54.721 | 84.846 | 1.00 | 19.45 | B | O |
| ATOM | 5145 | N | ALA | B | 740 | 9.168 | 56.465 | 85.408 | 1.00 | 21.20 | B | N |
| ATOM | 5146 | CA | ALA | B | 740 | 9.535 | 55.921 | 86.714 | 1.00 | 22.83 | B | C |
| ATOM | 5147 | CB | ALA | B | 740 | 10.498 | 56.863 | 87.426 | 1.00 | 20.51 | B | C |
| ATOM | 5148 | C | ALA | B | 740 | 8.282 | 55.712 | 87.561 | 1.00 | 23.24 | B | C |
| ATOM | 5149 | O | ALA | B | 740 | 8.127 | 54.677 | 88.207 | 1.00 | 23.02 | B | O |
| ATOM | 5150 | N | GLU | B | 741 | 7.384 | 56.691 | 87.548 | 1.00 | 22.97 | B | N |
| ATOM | 5151 | CA | GLU | B | 741 | 6.161 | 56.579 | 88.322 | 1.00 | 25.70 | B | C |
| ATOM | 5152 | CB | GLU | B | 741 | 5.374 | 57.888 | 88.263 | 1.00 | 27.81 | B | C |
| ATOM | 5153 | CG | GLU | B | 741 | 6.146 | 59.100 | 88.770 | 1.00 | 33.24 | B | C |
| ATOM | 5154 | CD | GLU | B | 741 | 6.111 | 59.229 | 90.285 | 1.00 | 34.83 | B | C |
| ATOM | 5155 | OE1 | GLU | B | 741 | 7.181 | 59.448 | 90.895 | 1.00 | 36.24 | B | O |
| ATOM | 5156 | OE2 | GLU | B | 741 | 5.011 | 59.111 | 90.867 | 1.00 | 38.00 | B | O |
| ATOM | 5157 | C | GLU | B | 741 | 5.290 | 55.432 | 87.817 | 1.00 | 26.64 | B | C |
| ATOM | 5158 | O | GLU | B | 741 | 4.625 | 54.757 | 88.601 | 1.00 | 25.82 | B | O |
| ATOM | 5159 | N | GLY | B | 742 | 5.302 | 55.208 | 86.506 | 1.00 | 27.81 | B | N |
| ATOM | 5160 | CA | GLY | B | 742 | 4.492 | 54.145 | 85.939 | 1.00 | 28.77 | B | C |
| ATOM | 5161 | C | GLY | B | 742 | 4.977 | 52.767 | 86.327 | 1.00 | 30.49 | B | C |
| ATOM | 5162 | O | GLY | B | 742 | 4.252 | 51.782 | 86.194 | 1.00 | 31.60 | B | O |
| ATOM | 5163 | N | LEU | B | 743 | 6.212 | 52.700 | 86.805 | 1.00 | 31.82 | B | N |
| ATOM | 5164 | CA | LEU | B | 743 | 6.824 | 51.443 | 87.215 | 1.00 | 32.61 | B | C |
| ATOM | 5165 | CB | LEU | B | 743 | 8.248 | 51.367 | 86.656 | 1.00 | 30.54 | B | C |
| ATOM | 5166 | CG | LEU | B | 743 | 8.531 | 50.628 | 85.345 | 1.00 | 29.34 | B | C |
| ATOM | 5167 | CD1 | LEU | B | 743 | 7.256 | 50.384 | 84.561 | 1.00 | 26.88 | B | C |
| ATOM | 5168 | CD2 | LEU | B | 743 | 9.522 | 51.449 | 84.543 | 1.00 | 28.28 | B | C |
| ATOM | 5169 | C | LEU | B | 743 | 6.876 | 51.357 | 88.743 | 1.00 | 34.95 | B | C |
| ATOM | 5170 | O | LEU | B | 743 | 7.170 | 50.305 | 89.310 | 1.00 | 34.20 | B | O |
| ATOM | 5171 | N | LYS | B | 744 | 6.585 | 52.480 | 89.394 | 1.00 | 38.15 | B | N |
| ATOM | 5172 | CA | LYS | B | 744 | 6.617 | 52.592 | 90.848 | 1.00 | 40.44 | B | C |
| ATOM | 5173 | CB | LYS | B | 744 | 6.283 | 54.029 | 91.253 | 1.00 | 39.14 | B | C |
| ATOM | 5174 | CG | LYS | B | 744 | 7.297 | 54.673 | 92.175 | 1.00 | 36.35 | B | C |
| ATOM | 5175 | CD | LYS | B | 744 | 6.602 | 55.500 | 93.230 | 1.00 | 35.55 | B | C |
| ATOM | 5176 | CE | LYS | B | 744 | 7.429 | 56.707 | 93.622 | 1.00 | 36.85 | B | C |
| ATOM | 5177 | NZ | LYS | B | 744 | 6.673 | 57.606 | 94.537 | 1.00 | 36.75 | B | N |
| ATOM | 5178 | C | LYS | B | 744 | 5.709 | 51.633 | 91.617 | 1.00 | 43.79 | B | C |
| ATOM | 5179 | O | LYS | B | 744 | 4.634 | 51.247 | 91.151 | 1.00 | 43.72 | B | O |
| ATOM | 5180 | N | SER | B | 745 | 6.162 | 51.264 | 92.811 | 1.00 | 47.35 | B | N |
| ATOM | 5181 | CA | SER | B | 745 | 5.424 | 50.372 | 93.695 | 1.00 | 51.17 | B | C |
| ATOM | 5182 | CB | SER | B | 745 | 5.232 | 49.004 | 93.036 | 1.00 | 52.44 | B | C |
| ATOM | 5183 | OG | SER | B | 745 | 3.990 | 48.436 | 93.416 | 1.00 | 55.13 | B | O |
| ATOM | 5184 | C | SER | B | 745 | 6.180 | 50.214 | 95.017 | 1.00 | 53.95 | B | C |
| ATOM | 5185 | O | SER | B | 745 | 6.983 | 49.257 | 95.129 | 1.00 | 55.53 | B | O |
| ATOM | 5186 | OT | SER | B | 745 | 5.966 | 51.054 | 95.926 | 1.00 | 54.80 | B | O |
| ATOM | 5187 | CB | SER | D | 106 | −10.669 | 60.597 | 13.674 | 1.00 | 41.29 | D | C |
| ATOM | 5188 | OG | SER | D | 106 | −11.671 | 60.084 | 14.533 | 1.00 | 42.38 | D | O |
| ATOM | 5189 | C | SER | D | 106 | −12.783 | 60.900 | 12.349 | 1.00 | 40.11 | D | C |
| ATOM | 5190 | O | SER | D | 106 | −13.463 | 61.793 | 12.858 | 1.00 | 40.79 | D | O |
| ATOM | 5191 | N | SER | D | 106 | −10.812 | 62.376 | 11.950 | 1.00 | 40.36 | D | N |
| ATOM | 5192 | CA | SER | D | 106 | −11.253 | 60.994 | 12.313 | 1.00 | 41.05 | D | C |
| ATOM | 5193 | N | PRO | D | 107 | −13.342 | 59.804 | 11.816 | 1.00 | 39.08 | D | N |
| ATOM | 5194 | CD | PRO | D | 107 | −12.628 | 58.666 | 11.214 | 1.00 | 38.12 | D | C |
| ATOM | 5195 | CA | PRO | D | 107 | −14.795 | 59.613 | 11.788 | 1.00 | 39.02 | D | C |
| ATOM | 5196 | CB | PRO | D | 107 | −14.975 | 58.287 | 11.042 | 1.00 | 37.27 | D | C |
| ATOM | 5197 | CG | PRO | D | 107 | −13.678 | 58.023 | 10.371 | 1.00 | 36.87 | D | C |
| ATOM | 5198 | C | PRO | D | 107 | −15.501 | 59.593 | 13.146 | 1.00 | 39.56 | D | C |
| ATOM | 5199 | O | PRO | D | 107 | −16.688 | 59.911 | 13.233 | 1.00 | 40.00 | D | O |
| ATOM | 5200 | N | THR | D | 108 | −14.781 | 59.231 | 14.203 | 1.00 | 39.18 | D | N |
| ATOM | 5201 | CA | THR | D | 108 | −15.384 | 59.144 | 15.533 | 1.00 | 38.91 | D | C |
| ATOM | 5202 | CB | THR | D | 108 | −14.545 | 58.217 | 16.461 | 1.00 | 39.32 | D | C |
| ATOM | 5203 | OG1 | THR | D | 108 | −13.377 | 58.910 | 16.922 | 1.00 | 39.24 | D | O |
| ATOM | 5204 | CG2 | THR | D | 108 | −14.124 | 56.959 | 15.708 | 1.00 | 38.63 | D | C |
| ATOM | 5205 | C | THR | D | 108 | −15.636 | 60.473 | 16.258 | 1.00 | 37.17 | D | C |
| ATOM | 5206 | O | THR | D | 108 | −16.125 | 60.482 | 17.390 | 1.00 | 37.25 | D | O |
| ATOM | 5207 | N | TYR | D | 109 | −15.328 | 61.592 | 15.610 | 1.00 | 35.89 | D | N |
| ATOM | 5208 | CA | TYR | D | 109 | −15.530 | 62.895 | 16.242 | 1.00 | 33.43 | D | C |
| ATOM | 5209 | CB | TYR | D | 109 | −14.306 | 63.784 | 16.015 | 1.00 | 32.34 | D | C |
| ATOM | 5210 | CG | TYR | D | 109 | −13.213 | 63.559 | 17.036 | 1.00 | 33.46 | D | C |
| ATOM | 5211 | CD1 | TYR | D | 109 | −12.881 | 62.269 | 17.459 | 1.00 | 34.48 | D | C |
| ATOM | 5212 | CE1 | TYR | D | 109 | −11.876 | 62.054 | 18.399 | 1.00 | 33.07 | D | C |
| ATOM | 5213 | CD2 | TYR | D | 109 | −12.511 | 64.629 | 17.584 | 1.00 | 32.05 | D | C |
| ATOM | 5214 | CE2 | TYR | D | 109 | −11.505 | 64.424 | 18.524 | 1.00 | 31.57 | D | C |
| ATOM | 5215 | CZ | TYR | D | 109 | −11.191 | 63.137 | 18.925 | 1.00 | 32.08 | D | C |
| ATOM | 5216 | OH | TYR | D | 109 | −10.183 | 62.930 | 19.839 | 1.00 | 33.44 | D | O |
| ATOM | 5217 | C | TYR | D | 109 | −16.788 | 63.611 | 15.765 | 1.00 | 31.68 | D | C |
| ATOM | 5218 | O | TYR | D | 109 | −17.006 | 64.780 | 16.082 | 1.00 | 31.61 | D | O |
| ATOM | 5219 | N | GLN | D | 110 | −17.621 | 62.901 | 15.015 | 1.00 | 30.55 | D | N |
| ATOM | 5220 | CA | GLN | D | 110 | −18.858 | 63.471 | 14.496 | 1.00 | 30.41 | D | C |
| ATOM | 5221 | CB | GLN | D | 110 | −19.642 | 62.420 | 13.696 | 1.00 | 31.07 | D | C |
| ATOM | 5222 | CG | GLN | D | 110 | −20.847 | 62.978 | 12.938 | 1.00 | 31.57 | D | C |
| ATOM | 5223 | CD | GLN | D | 110 | −20.447 | 63.878 | 11.776 | 1.00 | 30.74 | D | C |
| ATOM | 5224 | OE1 | GLN | D | 110 | −19.261 | 64.059 | 11.505 | 1.00 | 29.76 | D | O |
| ATOM | 5225 | NE2 | GLN | D | 110 | −21.437 | 64.445 | 11.087 | 1.00 | 28.31 | D | N |
| ATOM | 5226 | C | GLN | D | 110 | −19.725 | 63.970 | 15.634 | 1.00 | 29.69 | D | C |
| ATOM | 5227 | O | GLN | D | 110 | −20.608 | 64.810 | 15.441 | 1.00 | 30.20 | D | O |
| ATOM | 5228 | N | THR | D | 111 | −19.457 | 63.451 | 16.825 | 1.00 | 28.26 | D | N |
| ATOM | 5229 | CA | THR | D | 111 | −20.229 | 63.808 | 17.997 | 1.00 | 26.23 | D | C |
| ATOM | 5230 | CB | THR | D | 111 | −20.753 | 62.531 | 18.666 | 1.00 | 27.26 | D | C |
| ATOM | 5231 | OG1 | THR | D | 111 | −21.834 | 62.866 | 19.535 | 1.00 | 31.64 | D | O |
| ATOM | 5232 | CG2 | THR | D | 111 | −19.650 | 61.841 | 19.455 | 1.00 | 24.78 | D | C |
| ATOM | 5233 | C | THR | D | 111 | −19.454 | 64.655 | 19.014 | 1.00 | 25.56 | D | C |
| ATOM | 5234 | O | THR | D | 111 | −19.980 | 64.998 | 20.072 | 1.00 | 23.64 | D | O |
| ATOM | 5235 | N | VAL | D | 112 | −18.214 | 65.005 | 18.676 | 1.00 | 24.16 | D | N |
| ATOM | 5236 | CA | VAL | D | 112 | −17.359 | 65.811 | 19.553 | 1.00 | 22.09 | D | C |
| ATOM | 5237 | CB | VAL | D | 112 | −15.894 | 65.324 | 19.505 | 1.00 | 20.25 | D | C |
| ATOM | 5238 | CG1 | VAL | D | 112 | −15.042 | 66.139 | 20.465 | 1.00 | 20.03 | D | C |
| ATOM | 5239 | CG2 | VAL | D | 112 | −15.820 | 63.846 | 19.838 | 1.00 | 19.82 | D | C |
| ATOM | 5240 | C | VAL | D | 112 | −17.352 | 67.292 | 19.173 | 1.00 | 21.76 | D | C |
| ATOM | 5241 | O | VAL | D | 112 | −16.927 | 67.652 | 18.082 | 1.00 | 22.85 | D | O |
| ATOM | 5242 | N | PRO | D | 113 | −17.811 | 68.173 | 20.077 | 1.00 | 21.07 | D | N |
| ATOM | 5243 | CD | PRO | D | 113 | −18.354 | 67.878 | 21.411 | 1.00 | 18.73 | D | C |
| ATOM | 5244 | CA | PRO | D | 113 | −17.832 | 69.613 | 19.787 | 1.00 | 19.48 | D | C |
| ATOM | 5245 | CB | PRO | D | 113 | −18.597 | 70.213 | 20.966 | 1.00 | 18.54 | D | C |
| ATOM | 5246 | CG | PRO | D | 113 | −19.242 | 69.049 | 21.661 | 1.00 | 18.11 | D | C |
| ATOM | 5247 | C | PRO | D | 113 | −16.429 | 70.204 | 19.675 | 1.00 | 20.41 | D | C |
| ATOM | 5248 | O | PRO | D | 113 | −15.450 | 69.602 | 20.118 | 1.00 | 20.81 | D | O |
| ATOM | 5249 | N | ASP | D | 114 | −16.332 | 71.382 | 19.073 | 1.00 | 21.88 | D | N |
| ATOM | 5250 | CA | ASP | D | 114 | −15.048 | 72.050 | 18.937 | 1.00 | 23.29 | D | C |
| ATOM | 5251 | CB | ASP | D | 114 | −15.171 | 73.290 | 18.052 | 1.00 | 26.69 | D | C |
| ATOM | 5252 | CG | ASP | D | 114 | −15.324 | 72.961 | 16.582 | 1.00 | 30.64 | D | C |
| ATOM | 5253 | OD1 | ASP | D | 114 | −14.605 | 72.068 | 16.079 | 1.00 | 33.34 | D | O |
| ATOM | 5254 | OD2 | ASP | D | 114 | −16.169 | 73.609 | 15.924 | 1.00 | 32.70 | D | O |
| ATOM | 5255 | C | ASP | D | 114 | −14.622 | 72.516 | 20.320 | 1.00 | 23.25 | D | C |
| ATOM | 5256 | O | ASP | D | 114 | −15.465 | 72.760 | 21.178 | 1.00 | 25.42 | D | O |
| ATOM | 5257 | N | PHE | D | 115 | −13.316 | 72.631 | 20.534 | 1.00 | 21.37 | D | N |
| ATOM | 5258 | CA | PHE | D | 115 | −12.773 | 73.136 | 21.790 | 1.00 | 18.97 | D | C |
| ATOM | 5259 | CB | PHE | D | 115 | −13.006 | 72.150 | 22.961 | 1.00 | 17.11 | D | C |
| ATOM | 5260 | CG | PHE | D | 115 | −12.259 | 70.845 | 22.855 | 1.00 | 15.13 | D | C |
| ATOM | 5261 | CD1 | PHE | D | 115 | −12.829 | 69.752 | 22.209 | 1.00 | 14.27 | D | C |
| ATOM | 5262 | CD2 | PHE | D | 115 | −11.011 | 70.695 | 23.448 | 1.00 | 12.59 | D | C |
| ATOM | 5263 | CE1 | PHE | D | 115 | −12.166 | 68.530 | 22.159 | 1.00 | 14.02 | D | C |
| ATOM | 5264 | CE2 | PHE | D | 115 | −10.339 | 69.473 | 23.404 | 1.00 | 14.25 | D | C |
| ATOM | 5265 | CZ | PHE | D | 115 | −10.916 | 68.389 | 22.759 | 1.00 | 13.60 | D | C |
| ATOM | 5266 | C | PHE | D | 115 | −11.294 | 73.462 | 21.582 | 1.00 | 20.17 | D | C |
| ATOM | 5267 | O | PHE | D | 115 | −10.644 | 72.908 | 20.688 | 1.00 | 21.70 | D | O |
| ATOM | 5268 | N | GLN | D | 116 | −10.773 | 74.390 | 22.378 | 1.00 | 18.39 | D | N |
| ATOM | 5269 | CA | GLN | D | 116 | −9.388 | 74.800 | 22.248 | 1.00 | 16.82 | D | C |
| ATOM | 5270 | CB | GLN | D | 116 | −9.190 | 76.148 | 22.931 | 1.00 | 17.62 | D | C |
| ATOM | 5271 | CG | GLN | D | 116 | −10.058 | 77.234 | 22.320 | 1.00 | 17.93 | D | C |
| ATOM | 5272 | CD | GLN | D | 116 | −9.840 | 78.591 | 22.951 | 1.00 | 23.31 | D | C |
| ATOM | 5273 | OE1 | GLN | D | 116 | −10.433 | 78.904 | 23.982 | 1.00 | 24.53 | D | O |
| ATOM | 5274 | NE2 | GLN | D | 116 | −8.988 | 79.410 | 22.331 | 1.00 | 22.00 | D | N |
| ATOM | 5275 | C | GLN | D | 116 | −8.420 | 73.774 | 22.796 | 1.00 | 17.83 | D | C |
| ATOM | 5276 | O | GLN | D | 116 | −8.583 | 73.266 | 23.907 | 1.00 | 18.57 | D | O |
| ATOM | 5277 | N | ARG | D | 117 | −7.405 | 73.466 | 22.002 | 1.00 | 16.69 | D | N |
| ATOM | 5278 | CA | ARG | D | 117 | −6.413 | 72.494 | 22.406 | 1.00 | 18.27 | D | C |
| ATOM | 5279 | CB | ARG | D | 117 | −6.285 | 71.408 | 21.341 | 1.00 | 17.99 | D | C |
| ATOM | 5280 | CG | ARG | D | 117 | −7.473 | 70.461 | 21.314 | 1.00 | 20.17 | D | C |
| ATOM | 5281 | CD | ARG | D | 117 | −7.613 | 69.823 | 19.955 | 1.00 | 20.57 | D | C |
| ATOM | 5282 | NE | ARG | D | 117 | −8.531 | 68.690 | 19.965 | 1.00 | 20.76 | D | N |
| ATOM | 5283 | CZ | ARG | D | 117 | −9.779 | 68.743 | 19.515 | 1.00 | 20.87 | D | C |
| ATOM | 5284 | NH1 | ARG | D | 117 | −10.254 | 69.878 | 19.025 | 1.00 | 19.76 | D | N |
| ATOM | 5285 | NH2 | ARG | D | 117 | −10.544 | 67.657 | 19.533 | 1.00 | 21.17 | D | N |
| ATOM | 5286 | C | ARG | D | 117 | −5.069 | 73.146 | 22.643 | 1.00 | 17.47 | D | C |
| ATOM | 5287 | O | ARG | D | 117 | −4.796 | 74.244 | 22.152 | 1.00 | 16.85 | D | O |
| ATOM | 5288 | N | VAL | D | 118 | −4.231 | 72.475 | 23.419 | 1.00 | 18.33 | D | N |
| ATOM | 5289 | CA | VAL | D | 118 | −2.911 | 73.001 | 23.692 | 1.00 | 19.92 | D | C |
| ATOM | 5290 | CB | VAL | D | 118 | −2.594 | 73.029 | 25.228 | 1.00 | 19.52 | D | C |
| ATOM | 5291 | CG1 | VAL | D | 118 | −3.652 | 72.282 | 26.001 | 1.00 | 18.88 | D | C |
| ATOM | 5292 | CG2 | VAL | D | 118 | −1.209 | 72.464 | 25.502 | 1.00 | 17.70 | D | C |
| ATOM | 5293 | C | VAL | D | 118 | −1.911 | 72.124 | 22.961 | 1.00 | 21.06 | D | C |
| ATOM | 5294 | O | VAL | D | 118 | −1.897 | 70.906 | 23.129 | 1.00 | 20.33 | D | O |
| ATOM | 5295 | N | GLN | D | 119 | −1.086 | 72.742 | 22.127 | 1.00 | 22.13 | D | N |
| ATOM | 5296 | CA | GLN | D | 119 | −0.095 | 71.981 | 21.399 | 1.00 | 23.66 | D | C |
| ATOM | 5297 | CB | GLN | D | 119 | −0.453 | 71.880 | 19.915 | 1.00 | 27.62 | D | C |
| ATOM | 5298 | CG | GLN | D | 119 | −1.174 | 73.072 | 19.328 | 1.00 | 34.11 | D | C |
| ATOM | 5299 | CD | GLN | D | 119 | −1.305 | 72.955 | 17.813 | 1.00 | 38.99 | D | C |
| ATOM | 5300 | OE1 | GLN | D | 119 | −0.398 | 73.342 | 17.066 | 1.00 | 40.57 | D | O |
| ATOM | 5301 | NE2 | GLN | D | 119 | −2.429 | 72.408 | 17.354 | 1.00 | 36.83 | D | N |
| ATOM | 5302 | C | GLN | D | 119 | 1.283 | 72.578 | 21.565 | 1.00 | 21.98 | D | C |
| ATOM | 5303 | O | GLN | D | 119 | 1.441 | 73.784 | 21.738 | 1.00 | 21.91 | D | O |
| ATOM | 5304 | N | ILE | D | 120 | 2.274 | 71.700 | 21.529 | 1.00 | 20.02 | D | N |
| ATOM | 5305 | CA | ILE | D | 120 | 3.662 | 72.071 | 21.688 | 1.00 | 21.05 | D | C |
| ATOM | 5306 | CB | ILE | D | 120 | 4.362 | 71.123 | 22.692 | 1.00 | 18.08 | D | C |
| ATOM | 5307 | CG2 | ILE | D | 120 | 5.763 | 71.618 | 22.997 | 1.00 | 16.36 | D | C |
| ATOM | 5308 | CG1 | ILE | D | 120 | 3.517 | 70.995 | 23.965 | 1.00 | 18.01 | D | C |
| ATOM | 5309 | CD1 | ILE | D | 120 | 3.092 | 72.316 | 24.583 | 1.00 | 15.57 | D | C |
| ATOM | 5310 | C | ILE | D | 120 | 4.350 | 71.954 | 20.339 | 1.00 | 23.87 | D | C |
| ATOM | 5311 | O | ILE | D | 120 | 4.208 | 70.946 | 19.647 | 1.00 | 24.34 | D | O |
| ATOM | 5312 | N | THR | D | 121 | 5.092 | 72.991 | 19.970 | 1.00 | 26.48 | D | N |
| ATOM | 5313 | CA | THR | D | 121 | 5.821 | 73.007 | 18.708 | 1.00 | 28.63 | D | C |
| ATOM | 5314 | CB | THR | D | 121 | 5.735 | 74.383 | 18.040 | 1.00 | 27.26 | D | C |
| ATOM | 5315 | OG1 | THR | D | 121 | 6.532 | 75.316 | 18.774 | 1.00 | 27.75 | D | O |
| ATOM | 5316 | CG2 | THR | D | 121 | 4.302 | 74.870 | 18.010 | 1.00 | 28.06 | D | C |
| ATOM | 5317 | C | THR | D | 121 | 7.284 | 72.682 | 18.978 | 1.00 | 29.73 | D | C |
| ATOM | 5318 | O | THR | D | 121 | 7.738 | 72.767 | 20.114 | 1.00 | 31.64 | D | O |
| ATOM | 5319 | N | GLY | D | 122 | 8.015 | 72.292 | 17.941 | 1.00 | 32.19 | D | N |
| ATOM | 5320 | CA | GLY | D | 122 | 9.421 | 71.974 | 18.112 | 1.00 | 35.28 | D | C |
| ATOM | 5321 | C | GLY | D | 122 | 9.731 | 70.507 | 18.345 | 1.00 | 38.59 | D | C |
| ATOM | 5322 | O | GLY | D | 122 | 8.838 | 69.704 | 18.621 | 1.00 | 38.84 | D | O |
| ATOM | 5323 | N | ASP | D | 123 | 11.014 | 70.167 | 18.233 | 1.00 | 42.30 | D | N |
| ATOM | 5324 | CA | ASP | D | 123 | 11.494 | 68.798 | 18.422 | 1.00 | 45.49 | D | C |
| ATOM | 5325 | CB | ASP | D | 123 | 12.831 | 68.596 | 17.700 | 1.00 | 48.98 | D | C |
| ATOM | 5326 | CG | ASP | D | 123 | 12.716 | 68.756 | 16.194 | 1.00 | 52.99 | D | C |
| ATOM | 5327 | OD1 | ASP | D | 123 | 11.802 | 68.138 | 15.601 | 1.00 | 54.71 | D | O |
| ATOM | 5328 | OD2 | ASP | D | 123 | 13.539 | 69.498 | 15.606 | 1.00 | 55.34 | D | O |
| ATOM | 5329 | C | ASP | D | 123 | 11.686 | 68.518 | 19.903 | 1.00 | 46.24 | D | C |
| ATOM | 5330 | O | ASP | D | 123 | 12.225 | 69.355 | 20.631 | 1.00 | 46.27 | D | O |
| ATOM | 5331 | N | TYR | D | 124 | 11.263 | 67.338 | 20.345 | 1.00 | 45.25 | D | N |
| ATOM | 5332 | CA | TYR | D | 124 | 11.392 | 66.977 | 21.752 | 1.00 | 44.84 | D | C |
| ATOM | 5333 | CB | TYR | D | 124 | 10.417 | 65.848 | 22.096 | 1.00 | 42.28 | D | C |
| ATOM | 5334 | CG | TYR | D | 124 | 9.056 | 66.349 | 22.515 | 1.00 | 40.28 | D | C |
| ATOM | 5335 | CD1 | TYR | D | 124 | 8.030 | 66.491 | 21.584 | 1.00 | 38.64 | D | C |
| ATOM | 5336 | CE1 | TYR | D | 124 | 6.780 | 66.986 | 21.957 | 1.00 | 38.50 | D | C |
| ATOM | 5337 | CD2 | TYR | D | 124 | 8.800 | 66.712 | 23.836 | 1.00 | 37.48 | D | C |
| ATOM | 5338 | CE2 | TYR | D | 124 | 7.554 | 67.208 | 24.218 | 1.00 | 36.40 | D | C |
| ATOM | 5339 | CZ | TYR | D | 124 | 6.550 | 67.342 | 23.272 | 1.00 | 36.98 | D | C |
| ATOM | 5340 | OH | TYR | D | 124 | 5.319 | 67.837 | 23.634 | 1.00 | 35.23 | D | O |
| ATOM | 5341 | C | TYR | D | 124 | 12.817 | 66.575 | 22.123 | 1.00 | 46.13 | D | C |
| ATOM | 5342 | O | TYR | D | 124 | 13.302 | 65.542 | 21.612 | 1.00 | 47.08 | D | O |
| ATOM | 5343 | OT | TYR | D | 124 | 13.436 | 67.310 | 22.926 | 1.00 | 47.94 | D | O |
| ATOM | 5344 | CB | ASP | E | 132 | 20.466 | 59.129 | 27.264 | 1.00 | 55.90 | E | C |
| ATOM | 5345 | CG | ASP | E | 132 | 20.102 | 59.494 | 28.698 | 1.00 | 58.10 | E | C |
| ATOM | 5346 | OD1 | ASP | E | 132 | 19.200 | 60.343 | 28.885 | 1.00 | 59.02 | E | O |
| ATOM | 5347 | OD2 | ASP | E | 132 | 20.720 | 58.936 | 29.635 | 1.00 | 59.13 | E | O |
| ATOM | 5348 | C | ASP | E | 132 | 18.439 | 57.705 | 26.922 | 1.00 | 51.50 | E | C |
| ATOM | 5349 | O | ASP | E | 132 | 17.854 | 56.904 | 27.649 | 1.00 | 51.69 | E | O |
| ATOM | 5350 | N | ASP | E | 132 | 20.413 | 57.405 | 25.474 | 1.00 | 53.43 | E | N |
| ATOM | 5351 | CA | ASP | E | 132 | 19.959 | 57.738 | 26.860 | 1.00 | 53.54 | E | C |
| ATOM | 5352 | N | PHE | E | 133 | 17.806 | 58.585 | 26.155 | 1.00 | 50.07 | E | N |
| ATOM | 5353 | CA | PHE | E | 133 | 16.352 | 58.647 | 26.103 | 1.00 | 48.42 | E | C |
| ATOM | 5354 | CB | PHE | E | 133 | 15.905 | 59.834 | 25.241 | 1.00 | 46.40 | E | C |
| ATOM | 5355 | CG | PHE | E | 133 | 14.428 | 59.869 | 24.969 | 1.00 | 46.11 | E | C |
| ATOM | 5356 | CD1 | PHE | E | 133 | 13.953 | 60.099 | 23.677 | 1.00 | 44.99 | E | C |
| ATOM | 5357 | CD2 | PHE | E | 133 | 13.507 | 59.665 | 26.002 | 1.00 | 45.35 | E | C |
| ATOM | 5358 | CE1 | PHE | E | 133 | 12.581 | 60.125 | 23.412 | 1.00 | 44.34 | E | C |
| ATOM | 5359 | CE2 | PHE | E | 133 | 12.133 | 59.687 | 25.754 | 1.00 | 44.27 | E | C |
| ATOM | 5360 | CZ | PHE | E | 133 | 11.667 | 59.918 | 24.454 | 1.00 | 46.01 | E | C |
| ATOM | 5361 | C | PHE | E | 133 | 15.864 | 57.340 | 25.487 | 1.00 | 47.75 | E | C |
| ATOM | 5362 | O | PHE | E | 133 | 14.773 | 56.854 | 25.799 | 1.00 | 48.29 | E | O |
| ATOM | 5363 | N | GLU | E | 134 | 16.693 | 56.772 | 24.617 | 1.00 | 46.40 | E | N |
| ATOM | 5364 | CA | GLU | E | 134 | 16.366 | 55.524 | 23.950 | 1.00 | 45.22 | E | C |
| ATOM | 5365 | CB | GLU | E | 134 | 17.460 | 55.167 | 22.941 | 1.00 | 48.09 | E | C |
| ATOM | 5366 | CG | GLU | E | 134 | 16.934 | 54.575 | 21.643 | 1.00 | 52.30 | E | C |
| ATOM | 5367 | CD | GLU | E | 134 | 17.700 | 53.336 | 21.211 | 1.00 | 55.29 | E | C |
| ATOM | 5368 | OE1 | GLU | E | 134 | 18.808 | 53.103 | 21.745 | 1.00 | 57.14 | E | O |
| ATOM | 5369 | OE2 | GLU | E | 134 | 17.194 | 52.597 | 20.337 | 1.00 | 56.56 | E | O |
| ATOM | 5370 | C | GLU | E | 134 | 16.214 | 54.402 | 24.969 | 1.00 | 43.65 | E | C |
| ATOM | 5371 | O | GLU | E | 134 | 15.312 | 53.566 | 24.859 | 1.00 | 42.16 | E | O |
| ATOM | 5372 | N | ILE | E | 135 | 17.098 | 54.380 | 25.961 | 1.00 | 40.84 | E | N |
| ATOM | 5373 | CA | ILE | E | 135 | 17.038 | 53.346 | 26.982 | 1.00 | 38.86 | E | C |
| ATOM | 5374 | CB | ILE | E | 135 | 18.328 | 53.320 | 27.844 | 1.00 | 40.94 | E | C |
| ATOM | 5375 | CG2 | ILE | E | 135 | 19.534 | 53.677 | 26.986 | 1.00 | 40.80 | E | C |
| ATOM | 5376 | CG1 | ILE | E | 135 | 18.202 | 54.288 | 29.024 | 1.00 | 43.56 | E | C |
| ATOM | 5377 | CD1 | ILE | E | 135 | 17.801 | 53.620 | 30.333 | 1.00 | 44.41 | E | C |
| ATOM | 5378 | C | ILE | E | 135 | 15.825 | 53.582 | 27.870 | 1.00 | 36.56 | E | C |
| ATOM | 5379 | O | ILE | E | 135 | 15.274 | 52.648 | 28.454 | 1.00 | 36.80 | E | O |
| ATOM | 5380 | N | VAL | E | 136 | 15.408 | 54.839 | 27.969 | 1.00 | 34.51 | E | N |
| ATOM | 5381 | CA | VAL | E | 136 | 14.246 | 55.179 | 28.780 | 1.00 | 31.36 | E | C |
| ATOM | 5382 | CB | VAL | E | 136 | 14.120 | 56.711 | 28.978 | 1.00 | 29.67 | E | C |
| ATOM | 5383 | CG1 | VAL | E | 136 | 12.787 | 57.052 | 29.614 | 1.00 | 28.84 | E | C |
| ATOM | 5384 | CG2 | VAL | E | 136 | 15.250 | 57.213 | 29.848 | 1.00 | 28.78 | E | C |
| ATOM | 5385 | C | VAL | E | 136 | 12.998 | 54.659 | 28.073 | 1.00 | 29.93 | E | C |
| ATOM | 5386 | O | VAL | E | 136 | 12.127 | 54.053 | 28.696 | 1.00 | 28.92 | E | O |
| ATOM | 5387 | N | CYS | E | 137 | 12.923 | 54.894 | 26.765 | 1.00 | 28.66 | E | N |
| ATOM | 5388 | CA | CYS | E | 137 | 11.783 | 54.452 | 25.970 | 1.00 | 27.91 | E | C |
| ATOM | 5389 | CB | CYS | E | 137 | 11.894 | 55.002 | 24.548 | 1.00 | 28.13 | E | C |
| ATOM | 5390 | SG | CYS | E | 137 | 11.399 | 56.736 | 24.388 | 1.00 | 30.03 | E | S |
| ATOM | 5391 | C | CYS | E | 137 | 11.713 | 52.930 | 25.931 | 1.00 | 27.48 | E | C |
| ATOM | 5392 | O | CYS | E | 137 | 10.629 | 52.347 | 25.918 | 1.00 | 26.70 | E | O |
| ATOM | 5393 | N | LYS | E | 138 | 12.880 | 52.296 | 25.916 | 1.00 | 26.59 | E | N |
| ATOM | 5394 | CA | LYS | E | 138 | 12.967 | 50.844 | 25.879 | 1.00 | 26.15 | E | C |
| ATOM | 5395 | CB | LYS | E | 138 | 14.410 | 50.412 | 25.642 | 1.00 | 27.91 | E | C |
| ATOM | 5396 | CG | LYS | E | 138 | 14.882 | 50.611 | 24.213 | 1.00 | 34.72 | E | C |
| ATOM | 5397 | CD | LYS | E | 138 | 16.232 | 49.948 | 23.995 | 1.00 | 38.32 | E | C |
| ATOM | 5398 | CE | LYS | E | 138 | 16.688 | 50.081 | 22.554 | 1.00 | 40.92 | E | C |
| ATOM | 5399 | NZ | LYS | E | 138 | 17.201 | 48.782 | 22.030 | 1.00 | 42.63 | E | N |
| ATOM | 5400 | C | LYS | E | 138 | 12.461 | 50.231 | 27.179 | 1.00 | 24.52 | E | C |
| ATOM | 5401 | O | LYS | E | 138 | 11.817 | 49.183 | 27.167 | 1.00 | 23.48 | E | O |
| ATOM | 5402 | N | GLY | E | 139 | 12.763 | 50.885 | 28.299 | 1.00 | 23.18 | E | N |
| ATOM | 5403 | CA | GLY | E | 139 | 12.326 | 50.390 | 29.593 | 1.00 | 22.05 | E | C |
| ATOM | 5404 | C | GLY | E | 139 | 10.821 | 50.486 | 29.743 | 1.00 | 21.53 | E | C |
| ATOM | 5405 | O | GLY | E | 139 | 10.171 | 49.541 | 30.196 | 1.00 | 22.54 | E | O |
| ATOM | 5406 | N | LEU | E | 140 | 10.264 | 51.629 | 29.354 | 1.00 | 20.41 | E | N |
| ATOM | 5407 | CA | LEU | E | 140 | 8.825 | 51.849 | 29.440 | 1.00 | 20.30 | E | C |
| ATOM | 5408 | CB | LEU | E | 140 | 8.490 | 53.292 | 29.055 | 1.00 | 20.81 | E | C |
| ATOM | 5409 | CG | LEU | E | 140 | 8.910 | 54.353 | 30.085 | 1.00 | 20.83 | E | C |
| ATOM | 5410 | CD1 | LEU | E | 140 | 8.580 | 55.744 | 29.566 | 1.00 | 19.09 | E | C |
| ATOM | 5411 | CD2 | LEU | E | 140 | 8.196 | 54.107 | 31.403 | 1.00 | 18.29 | E | C |
| ATOM | 5412 | C | LEU | E | 140 | 8.083 | 50.870 | 28.534 | 1.00 | 20.91 | E | C |
| ATOM | 5413 | O | LEU | E | 140 | 7.009 | 50.370 | 28.887 | 1.00 | 19.88 | E | O |
| ATOM | 5414 | N | TYR | E | 141 | 8.663 | 50.589 | 27.369 | 1.00 | 20.71 | E | N |
| ATOM | 5415 | CA | TYR | E | 141 | 8.059 | 49.651 | 26.433 | 1.00 | 19.10 | E | C |
| ATOM | 5416 | CB | TYR | E | 141 | 8.877 | 49.593 | 25.136 | 1.00 | 20.13 | E | C |
| ATOM | 5417 | CG | TYR | E | 141 | 8.578 | 48.375 | 24.291 | 1.00 | 19.99 | E | C |
| ATOM | 5418 | CD1 | TYR | E | 141 | 9.451 | 47.295 | 24.269 | 1.00 | 21.78 | E | C |
| ATOM | 5419 | CE1 | TYR | E | 141 | 9.161 | 46.150 | 23.532 | 1.00 | 24.21 | E | C |
| ATOM | 5420 | CD2 | TYR | E | 141 | 7.400 | 48.287 | 23.547 | 1.00 | 21.54 | E | C |
| ATOM | 5421 | CE2 | TYR | E | 141 | 7.098 | 47.147 | 22.806 | 1.00 | 21.21 | E | C |
| ATOM | 5422 | CZ | TYR | E | 141 | 7.983 | 46.081 | 22.809 | 1.00 | 23.83 | E | C |
| ATOM | 5423 | OH | TYR | E | 141 | 7.683 | 44.926 | 22.124 | 1.00 | 29.70 | E | O |
| ATOM | 5424 | C | TYR | E | 141 | 7.990 | 48.258 | 27.062 | 1.00 | 17.83 | E | C |
| ATOM | 5425 | O | TYR | E | 141 | 6.942 | 47.616 | 27.061 | 1.00 | 18.08 | E | O |
| ATOM | 5426 | N | ARG | E | 142 | 9.108 | 47.795 | 27.610 | 1.00 | 17.63 | E | N |
| ATOM | 5427 | CA | ARG | E | 142 | 9.152 | 46.474 | 28.220 | 1.00 | 18.91 | E | C |
| ATOM | 5428 | CB | ARG | E | 142 | 10.588 | 46.108 | 28.601 | 1.00 | 19.65 | E | C |
| ATOM | 5429 | CG | ARG | E | 142 | 10.659 | 44.969 | 29.597 | 1.00 | 23.14 | E | C |
| ATOM | 5430 | CD | ARG | E | 142 | 11.959 | 44.184 | 29.530 | 1.00 | 23.17 | E | C |
| ATOM | 5431 | NE | ARG | E | 142 | 11.839 | 42.972 | 30.338 | 1.00 | 27.01 | E | N |
| ATOM | 5432 | CZ | ARG | E | 142 | 12.836 | 42.394 | 31.000 | 1.00 | 27.89 | E | C |
| ATOM | 5433 | NH1 | ARG | E | 142 | 14.056 | 42.919 | 30.955 | 1.00 | 26.08 | E | N |
| ATOM | 5434 | NH2 | ARG | E | 142 | 12.603 | 41.296 | 31.719 | 1.00 | 24.05 | E | N |
| ATOM | 5435 | C | ARG | E | 142 | 8.245 | 46.370 | 29.444 | 1.00 | 18.90 | E | C |
| ATOM | 5436 | O | ARG | E | 142 | 7.664 | 45.318 | 29.704 | 1.00 | 19.56 | E | O |
| ATOM | 5437 | N | ALA | E | 143 | 8.119 | 47.460 | 30.195 | 1.00 | 18.59 | E | N |
| ATOM | 5438 | CA | ALA | E | 143 | 7.262 | 47.463 | 31.379 | 1.00 | 17.74 | E | C |
| ATOM | 5439 | CB | ALA | E | 143 | 7.426 | 48.768 | 32.141 | 1.00 | 17.02 | E | C |
| ATOM | 5440 | C | ALA | E | 143 | 5.799 | 47.264 | 30.981 | 1.00 | 17.84 | E | C |
| ATOM | 5441 | O | ALA | E | 143 | 5.061 | 46.526 | 31.640 | 1.00 | 16.49 | E | O |
| ATOM | 5442 | N | LEU | E | 144 | 5.381 | 47.922 | 29.901 | 1.00 | 17.57 | E | N |
| ATOM | 5443 | CA | LEU | E | 144 | 4.008 | 47.794 | 29.422 | 1.00 | 15.69 | E | C |
| ATOM | 5444 | CB | LEU | E | 144 | 3.723 | 48.859 | 28.358 | 1.00 | 16.26 | E | C |
| ATOM | 5445 | CG | LEU | E | 144 | 3.518 | 50.286 | 28.879 | 1.00 | 16.60 | E | C |
| ATOM | 5446 | CD1 | LEU | E | 144 | 3.467 | 51.277 | 27.733 | 1.00 | 15.16 | E | C |
| ATOM | 5447 | CD2 | LEU | E | 144 | 2.228 | 50.341 | 29.685 | 1.00 | 15.48 | E | C |
| ATOM | 5448 | C | LEU | E | 144 | 3.796 | 46.396 | 28.842 | 1.00 | 16.46 | E | C |
| ATOM | 5449 | O | LEU | E | 144 | 2.698 | 45.837 | 28.906 | 1.00 | 15.41 | E | O |
| ATOM | 5450 | N | CYS | E | 145 | 4.862 | 45.834 | 28.278 | 1.00 | 17.96 | E | N |
| ATOM | 5451 | CA | CYS | E | 145 | 4.811 | 44.503 | 27.695 | 1.00 | 20.44 | E | C |
| ATOM | 5452 | CB | CYS | E | 145 | 6.093 | 44.212 | 26.914 | 1.00 | 24.87 | E | C |
| ATOM | 5453 | SG | CYS | E | 145 | 5.913 | 44.383 | 25.128 | 1.00 | 36.37 | E | S |
| ATOM | 5454 | C | CYS | E | 145 | 4.648 | 43.470 | 28.797 | 1.00 | 18.91 | E | C |
| ATOM | 5455 | O | CYS | E | 145 | 3.917 | 42.490 | 28.642 | 1.00 | 19.87 | E | O |
| ATOM | 5456 | N | ILE | E | 146 | 5.344 | 43.690 | 29.907 | 1.00 | 17.09 | E | N |
| ATOM | 5457 | CA | ILE | E | 146 | 5.265 | 42.789 | 31.048 | 1.00 | 16.09 | E | C |
| ATOM | 5458 | CB | ILE | E | 146 | 6.231 | 43.236 | 32.170 | 1.00 | 16.08 | E | C |
| ATOM | 5459 | CG2 | ILE | E | 146 | 5.852 | 42.581 | 33.492 | 1.00 | 17.04 | E | C |
| ATOM | 5460 | CG1 | ILE | E | 146 | 7.664 | 42.863 | 31.792 | 1.00 | 13.93 | E | C |
| ATOM | 5461 | CD1 | ILE | E | 146 | 8.716 | 43.631 | 32.547 | 1.00 | 11.86 | E | C |
| ATOM | 5462 | C | ILE | E | 146 | 3.834 | 42.758 | 31.588 | 1.00 | 16.39 | E | C |
| ATOM | 5463 | O | ILE | E | 146 | 3.260 | 41.681 | 31.779 | 1.00 | 18.27 | E | O |
| ATOM | 5464 | N | ARG | E | 147 | 3.244 | 43.931 | 31.812 | 1.00 | 15.38 | E | N |
| ATOM | 5465 | CA | ARG | E | 147 | 1.883 | 43.979 | 32.343 | 1.00 | 15.50 | E | C |
| ATOM | 5466 | CB | ARG | E | 147 | 1.461 | 45.417 | 32.663 | 1.00 | 12.81 | E | C |
| ATOM | 5467 | CG | ARG | E | 147 | −0.028 | 45.510 | 33.037 | 1.00 | 11.26 | E | C |
| ATOM | 5468 | CD | ARG | E | 147 | −0.393 | 46.784 | 33.765 | 1.00 | 8.01 | E | C |
| ATOM | 5469 | NE | ARG | E | 147 | −1.809 | 46.808 | 34.146 | 1.00 | 9.56 | E | N |
| ATOM | 5470 | CZ | ARG | E | 147 | −2.312 | 46.233 | 35.239 | 1.00 | 9.35 | E | C |
| ATOM | 5471 | NH1 | ARG | E | 147 | −1.514 | 45.574 | 36.075 | 1.00 | 8.24 | E | N |
| ATOM | 5472 | NH2 | ARG | E | 147 | −3.612 | 46.332 | 35.509 | 1.00 | 7.25 | E | N |
| ATOM | 5473 | C | ARG | E | 147 | 0.856 | 43.353 | 31.401 | 1.00 | 16.44 | E | C |
| ATOM | 5474 | O | ARG | E | 147 | −0.029 | 42.609 | 31.843 | 1.00 | 17.41 | E | O |
| ATOM | 5475 | N | GLU | E | 148 | 0.962 | 43.666 | 30.109 | 1.00 | 17.13 | E | N |
| ATOM | 5476 | CA | GLU | E | 148 | 0.040 | 43.117 | 29.113 | 1.00 | 16.79 | E | C |
| ATOM | 5477 | CB | GLU | E | 148 | 0.394 | 43.613 | 27.707 | 1.00 | 17.91 | E | C |
| ATOM | 5478 | CG | GLU | E | 148 | −0.491 | 43.001 | 26.617 | 1.00 | 17.92 | E | C |
| ATOM | 5479 | CD | GLU | E | 148 | 0.020 | 43.260 | 25.214 | 1.00 | 20.62 | E | C |
| ATOM | 5480 | OE1 | GLU | E | 148 | −0.747 | 43.811 | 24.392 | 1.00 | 21.66 | E | O |
| ATOM | 5481 | OE2 | GLU | E | 148 | 1.186 | 42.914 | 24.931 | 1.00 | 20.32 | E | O |
| ATOM | 5482 | C | GLU | E | 148 | 0.083 | 41.595 | 29.112 | 1.00 | 17.57 | E | C |
| ATOM | 5483 | O | GLU | E | 148 | −0.950 | 40.935 | 29.038 | 1.00 | 18.77 | E | O |
| ATOM | 5484 | N | LYS | E | 149 | 1.291 | 41.044 | 29.189 | 1.00 | 18.36 | E | N |
| ATOM | 5485 | CA | LYS | E | 149 | 1.484 | 39.602 | 29.200 | 1.00 | 19.14 | E | C |
| ATOM | 5486 | CB | LYS | E | 149 | 2.981 | 39.285 | 29.190 | 1.00 | 19.20 | E | C |
| ATOM | 5487 | CG | LYS | E | 149 | 3.307 | 37.798 | 29.230 | 1.00 | 22.61 | E | C |
| ATOM | 5488 | CD | LYS | E | 149 | 4.810 | 37.552 | 29.210 | 1.00 | 24.77 | E | C |
| ATOM | 5489 | CE | LYS | E | 149 | 5.480 | 38.102 | 30.476 | 1.00 | 29.86 | E | C |
| ATOM | 5490 | NZ | LYS | E | 149 | 6.969 | 37.878 | 30.519 | 1.00 | 29.93 | E | N |
| ATOM | 5491 | C | LYS | E | 149 | 0.822 | 38.936 | 30.407 | 1.00 | 21.10 | E | C |
| ATOM | 5492 | O | LYS | E | 149 | 0.087 | 37.952 | 30.258 | 1.00 | 22.47 | E | O |
| ATOM | 5493 | N | TYR | E | 150 | 1.077 | 39.476 | 31.599 | 1.00 | 20.33 | E | N |
| ATOM | 5494 | CA | TYR | E | 150 | 0.520 | 38.918 | 32.823 | 1.00 | 19.30 | E | C |
| ATOM | 5495 | CB | TYR | E | 150 | 1.223 | 39.537 | 34.039 | 1.00 | 23.47 | E | C |
| ATOM | 5496 | CG | TYR | E | 150 | 2.644 | 39.042 | 34.216 | 1.00 | 24.78 | E | C |
| ATOM | 5497 | CD1 | TYR | E | 150 | 2.934 | 37.986 | 35.072 | 1.00 | 26.89 | E | C |
| ATOM | 5498 | CE1 | TYR | E | 150 | 4.236 | 37.484 | 35.183 | 1.00 | 27.87 | E | C |
| ATOM | 5499 | CD2 | TYR | E | 150 | 3.693 | 39.594 | 33.480 | 1.00 | 26.69 | E | C |
| ATOM | 5500 | CE2 | TYR | E | 150 | 4.994 | 39.101 | 33.588 | 1.00 | 25.64 | E | C |
| ATOM | 5501 | CZ | TYR | E | 150 | 5.254 | 38.047 | 34.436 | 1.00 | 25.48 | E | C |
| ATOM | 5502 | OH | TYR | E | 150 | 6.524 | 37.536 | 34.521 | 1.00 | 27.21 | E | O |
| ATOM | 5503 | C | TYR | E | 150 | −0.986 | 39.100 | 32.922 | 1.00 | 18.18 | E | C |
| ATOM | 5504 | O | TYR | E | 150 | −1.674 | 38.282 | 33.529 | 1.00 | 18.34 | E | O |
| ATOM | 5505 | N | MET | E | 151 | −1.507 | 40.165 | 32.322 | 1.00 | 18.51 | E | N |
| ATOM | 5506 | CA | MET | E | 151 | −2.945 | 40.405 | 32.357 | 1.00 | 18.26 | E | C |
| ATOM | 5507 | CB | MET | E | 151 | −3.261 | 41.830 | 31.893 | 1.00 | 17.67 | E | C |
| ATOM | 5508 | CG | MET | E | 151 | −2.975 | 42.916 | 32.929 | 1.00 | 20.31 | E | C |
| ATOM | 5509 | SD | MET | E | 151 | −3.658 | 42.617 | 34.599 | 1.00 | 17.34 | E | S |
| ATOM | 5510 | CE | MET | E | 151 | −2.209 | 41.993 | 35.441 | 1.00 | 13.60 | E | C |
| ATOM | 5511 | C | MET | E | 151 | −3.689 | 39.399 | 31.472 | 1.00 | 18.97 | E | C |
| ATOM | 5512 | O | MET | E | 151 | −4.649 | 38.761 | 31.904 | 1.00 | 20.22 | E | O |
| ATOM | 5513 | N | LEU | E | 152 | −3.243 | 39.254 | 30.228 | 1.00 | 20.56 | E | N |
| ATOM | 5514 | CA | LEU | E | 152 | −3.883 | 38.327 | 29.294 | 1.00 | 21.11 | E | C |
| ATOM | 5515 | CB | LEU | E | 152 | −3.260 | 38.467 | 27.900 | 1.00 | 23.08 | E | C |
| ATOM | 5516 | CG | LEU | E | 152 | −3.325 | 39.856 | 27.252 | 1.00 | 26.12 | E | C |
| ATOM | 5517 | CD1 | LEU | E | 152 | −2.839 | 39.769 | 25.814 | 1.00 | 26.32 | E | C |
| ATOM | 5518 | CD2 | LEU | E | 152 | −4.751 | 40.388 | 27.304 | 1.00 | 26.30 | E | C |
| ATOM | 5519 | C | LEU | E | 152 | −3.764 | 36.882 | 29.755 | 1.00 | 20.39 | E | C |
| ATOM | 5520 | O | LEU | E | 152 | −4.705 | 36.099 | 29.631 | 1.00 | 21.39 | E | O |
| ATOM | 5521 | N | LYS | E | 153 | −2.602 | 36.534 | 30.293 | 1.00 | 20.26 | E | N |
| ATOM | 5522 | CA | LYS | E | 153 | −2.347 | 35.183 | 30.762 | 1.00 | 21.55 | E | C |
| ATOM | 5523 | CB | LYS | E | 153 | −0.876 | 35.048 | 31.142 | 1.00 | 23.55 | E | C |
| ATOM | 5524 | CG | LYS | E | 153 | −0.458 | 33.634 | 31.489 | 1.00 | 27.80 | E | C |
| ATOM | 5525 | CD | LYS | E | 153 | 0.930 | 33.602 | 32.119 | 1.00 | 31.83 | E | C |
| ATOM | 5526 | CE | LYS | E | 153 | 1.960 | 34.332 | 31.263 | 1.00 | 33.99 | E | C |
| ATOM | 5527 | NZ | LYS | E | 153 | 3.138 | 34.764 | 32.076 | 1.00 | 38.65 | E | N |
| ATOM | 5528 | C | LYS | E | 153 | −3.226 | 34.765 | 31.941 | 1.00 | 22.20 | E | C |
| ATOM | 5529 | O | LYS | E | 153 | −3.386 | 33.573 | 32.203 | 1.00 | 22.27 | E | O |
| ATOM | 5530 | N | SER | E | 154 | −3.793 | 35.740 | 32.649 | 1.00 | 21.57 | E | N |
| ATOM | 5531 | CA | SER | E | 154 | −4.640 | 35.446 | 33.802 | 1.00 | 21.43 | E | C |
| ATOM | 5532 | CB | SER | E | 154 | −4.113 | 36.148 | 35.062 | 1.00 | 21.16 | E | C |
| ATOM | 5533 | OG | SER | E | 154 | −4.048 | 37.560 | 34.891 | 1.00 | 21.17 | E | O |
| ATOM | 5534 | C | SER | E | 154 | −6.070 | 35.872 | 33.555 | 1.00 | 22.13 | E | C |
| ATOM | 5535 | O | SER | E | 154 | −6.878 | 35.922 | 34.486 | 1.00 | 23.81 | E | O |
| ATOM | 5536 | N | PHE | E | 155 | −6.378 | 36.185 | 32.300 | 1.00 | 19.82 | E | N |
| ATOM | 5537 | CA | PHE | E | 155 | −7.718 | 36.599 | 31.920 | 1.00 | 17.90 | E | C |
| ATOM | 5538 | CB | PHE | E | 155 | −8.701 | 35.455 | 32.163 | 1.00 | 20.09 | E | C |
| ATOM | 5539 | CG | PHE | E | 155 | −8.426 | 34.251 | 31.314 | 1.00 | 24.26 | E | C |
| ATOM | 5540 | CD1 | PHE | E | 155 | −8.994 | 34.131 | 30.047 | 1.00 | 25.61 | E | C |
| ATOM | 5541 | CD2 | PHE | E | 155 | −7.543 | 33.267 | 31.751 | 1.00 | 24.73 | E | C |
| ATOM | 5542 | CE1 | PHE | E | 155 | −8.680 | 33.047 | 29.223 | 1.00 | 26.33 | E | C |
| ATOM | 5543 | CE2 | PHE | E | 155 | −7.223 | 32.181 | 30.934 | 1.00 | 25.77 | E | C |
| ATOM | 5544 | CZ | PHE | E | 155 | −7.792 | 32.073 | 29.668 | 1.00 | 26.57 | E | C |
| ATOM | 5545 | C | PHE | E | 155 | −8.186 | 37.863 | 32.620 | 1.00 | 16.79 | E | C |
| ATOM | 5546 | O | PHE | E | 155 | −9.357 | 38.003 | 32.974 | 1.00 | 15.69 | E | O |
| ATOM | 5547 | N | GLN | E | 156 | −7.258 | 38.788 | 32.816 | 1.00 | 15.78 | E | N |
| ATOM | 5548 | CA | GLN | E | 156 | −7.584 | 40.058 | 33.434 | 1.00 | 16.89 | E | C |
| ATOM | 5549 | CB | GLN | E | 156 | −6.614 | 40.356 | 34.575 | 1.00 | 15.32 | E | C |
| ATOM | 5550 | CG | GLN | E | 156 | −6.851 | 39.428 | 35.774 | 1.00 | 14.10 | E | C |
| ATOM | 5551 | CD | GLN | E | 156 | −6.087 | 39.846 | 37.009 | 1.00 | 16.60 | E | C |
| ATOM | 5552 | OE1 | GLN | E | 156 | −4.885 | 39.580 | 37.136 | 1.00 | 15.26 | E | O |
| ATOM | 5553 | NE2 | GLN | E | 156 | −6.777 | 40.506 | 37.933 | 1.00 | 12.97 | E | N |
| ATOM | 5554 | C | GLN | E | 156 | −7.521 | 41.103 | 32.326 | 1.00 | 18.29 | E | C |
| ATOM | 5555 | O | GLN | E | 156 | −7.062 | 40.806 | 31.220 | 1.00 | 19.61 | E | O |
| ATOM | 5556 | N | ARG | E | 157 | −7.977 | 42.318 | 32.608 | 1.00 | 18.67 | E | N |
| ATOM | 5557 | CA | ARG | E | 157 | −8.024 | 43.364 | 31.590 | 1.00 | 17.68 | E | C |
| ATOM | 5558 | CB | ARG | E | 157 | −9.231 | 44.268 | 31.875 | 1.00 | 16.17 | E | C |
| ATOM | 5559 | CG | ARG | E | 157 | −10.526 | 43.479 | 32.117 | 1.00 | 15.56 | E | C |
| ATOM | 5560 | CD | ARG | E | 157 | −11.677 | 44.362 | 32.615 | 1.00 | 15.04 | E | C |
| ATOM | 5561 | NE | ARG | E | 157 | −11.448 | 44.854 | 33.973 | 1.00 | 14.94 | E | N |
| ATOM | 5562 | CZ | ARG | E | 157 | −12.302 | 45.610 | 34.653 | 1.00 | 12.63 | E | C |
| ATOM | 5563 | NH1 | ARG | E | 157 | −12.003 | 46.010 | 35.878 | 1.00 | 13.30 | E | N |
| ATOM | 5564 | NH2 | ARG | E | 157 | −13.454 | 45.965 | 34.117 | 1.00 | 13.39 | E | N |
| ATOM | 5565 | C | ARG | E | 157 | −6.786 | 44.224 | 31.332 | 1.00 | 18.61 | E | C |
| ATOM | 5566 | O | ARG | E | 157 | −5.986 | 44.493 | 32.235 | 1.00 | 18.47 | E | O |
| ATOM | 5567 | N | PHE | E | 158 | −6.639 | 44.627 | 30.066 | 1.00 | 18.70 | E | N |
| ATOM | 5568 | CA | PHE | E | 158 | −5.563 | 45.507 | 29.593 | 1.00 | 17.10 | E | C |
| ATOM | 5569 | CB | PHE | E | 158 | −4.339 | 44.719 | 29.139 | 1.00 | 15.37 | E | C |
| ATOM | 5570 | CG | PHE | E | 158 | −3.119 | 45.581 | 28.909 | 1.00 | 16.11 | E | C |
| ATOM | 5571 | CD1 | PHE | E | 158 | −2.738 | 45.945 | 27.621 | 1.00 | 14.94 | E | C |
| ATOM | 5572 | CD2 | PHE | E | 158 | −2.354 | 46.031 | 29.981 | 1.00 | 15.16 | E | C |
| ATOM | 5573 | CE1 | PHE | E | 158 | −1.613 | 46.743 | 27.397 | 1.00 | 14.06 | E | C |
| ATOM | 5574 | CE2 | PHE | E | 158 | −1.225 | 46.830 | 29.769 | 1.00 | 17.07 | E | C |
| ATOM | 5575 | CZ | PHE | E | 158 | −0.856 | 47.186 | 28.468 | 1.00 | 16.15 | E | C |
| ATOM | 5576 | C | PHE | E | 158 | −6.140 | 46.291 | 28.412 | 1.00 | 16.86 | E | C |
| ATOM | 5577 | O | PHE | E | 158 | −6.645 | 45.700 | 27.470 | 1.00 | 16.49 | E | O |
| ATOM | 5578 | N | PRO | E | 159 | −6.069 | 47.633 | 28.453 | 1.00 | 18.06 | E | N |
| ATOM | 5579 | CD | PRO | E | 159 | −5.430 | 48.424 | 29.517 | 1.00 | 15.54 | E | C |
| ATOM | 5580 | CA | PRO | E | 159 | −6.598 | 48.496 | 27.388 | 1.00 | 18.63 | E | C |
| ATOM | 5581 | CB | PRO | E | 159 | −6.245 | 49.907 | 27.858 | 1.00 | 18.12 | E | C |
| ATOM | 5582 | CG | PRO | E | 159 | −5.122 | 49.708 | 28.831 | 1.00 | 18.00 | E | C |
| ATOM | 5583 | C | PRO | E | 159 | −6.071 | 48.209 | 25.979 | 1.00 | 19.26 | E | C |
| ATOM | 5584 | O | PRO | E | 159 | −4.940 | 47.757 | 25.798 | 1.00 | 19.25 | E | O |
| ATOM | 5585 | N | LYS | E | 160 | −6.909 | 48.492 | 24.986 | 1.00 | 20.34 | E | N |
| ATOM | 5586 | CA | LYS | E | 160 | −6.568 | 48.264 | 23.590 | 1.00 | 20.49 | E | C |
| ATOM | 5587 | CB | LYS | E | 160 | −7.829 | 48.314 | 22.724 | 1.00 | 21.58 | E | C |
| ATOM | 5588 | CG | LYS | E | 160 | −8.610 | 47.013 | 22.699 | 1.00 | 24.21 | E | C |
| ATOM | 5589 | CD | LYS | E | 160 | −10.029 | 47.196 | 22.150 | 1.00 | 28.80 | E | C |
| ATOM | 5590 | CE | LYS | E | 160 | −10.705 | 48.464 | 22.681 | 1.00 | 30.32 | E | C |
| ATOM | 5591 | NZ | LYS | E | 160 | −11.393 | 48.248 | 23.988 | 1.00 | 33.31 | E | N |
| ATOM | 5592 | C | LYS | E | 160 | −5.546 | 49.237 | 23.024 | 1.00 | 19.89 | E | C |
| ATOM | 5593 | O | LYS | E | 160 | −4.567 | 48.811 | 22.416 | 1.00 | 21.33 | E | O |
| ATOM | 5594 | N | THR | E | 161 | −5.744 | 50.537 | 23.226 | 1.00 | 18.75 | E | N |
| ATOM | 5595 | CA | THR | E | 161 | −4.807 | 51.482 | 22.643 | 1.00 | 20.14 | E | C |
| ATOM | 5596 | CB | THR | E | 161 | −5.220 | 52.959 | 22.896 | 1.00 | 19.18 | E | C |
| ATOM | 5597 | OG1 | THR | E | 161 | −4.395 | 53.535 | 23.904 | 1.00 | 25.71 | E | O |
| ATOM | 5598 | CG2 | THR | E | 161 | −6.663 | 53.045 | 23.289 | 1.00 | 17.89 | E | C |
| ATOM | 5599 | C | THR | E | 161 | −3.342 | 51.250 | 22.997 | 1.00 | 19.98 | E | C |
| ATOM | 5600 | O | THR | E | 161 | −2.484 | 51.348 | 22.124 | 1.00 | 21.98 | E | O |
| ATOM | 5601 | N | PRO | E | 162 | −3.020 | 50.948 | 24.269 | 1.00 | 19.45 | E | N |
| ATOM | 5602 | CD | PRO | E | 162 | −3.834 | 50.834 | 25.488 | 1.00 | 19.54 | E | C |
| ATOM | 5603 | CA | PRO | E | 162 | −1.593 | 50.720 | 24.545 | 1.00 | 19.15 | E | C |
| ATOM | 5604 | CB | PRO | E | 162 | −1.539 | 50.503 | 26.061 | 1.00 | 17.78 | E | C |
| ATOM | 5605 | CG | PRO | E | 162 | −2.825 | 51.031 | 26.576 | 1.00 | 16.21 | E | C |
| ATOM | 5606 | C | PRO | E | 162 | −1.086 | 49.490 | 23.773 | 1.00 | 18.08 | E | C |
| ATOM | 5607 | O | PRO | E | 162 | 0.062 | 49.431 | 23.355 | 1.00 | 18.13 | E | O |
| ATOM | 5608 | N | SER | E | 163 | −1.959 | 48.507 | 23.592 | 1.00 | 20.00 | E | N |
| ATOM | 5609 | CA | SER | E | 163 | −1.605 | 47.293 | 22.866 | 1.00 | 21.64 | E | C |
| ATOM | 5610 | CB | SER | E | 163 | −2.751 | 46.288 | 22.943 | 1.00 | 23.09 | E | C |
| ATOM | 5611 | OG | SER | E | 163 | −2.829 | 45.712 | 24.238 | 1.00 | 26.33 | E | O |
| ATOM | 5612 | C | SER | E | 163 | −1.315 | 47.635 | 21.407 | 1.00 | 21.97 | E | C |
| ATOM | 5613 | O | SER | E | 163 | −0.333 | 47.164 | 20.830 | 1.00 | 20.99 | E | O |
| ATOM | 5614 | N | LYS | E | 164 | −2.176 | 48.461 | 20.820 | 1.00 | 20.88 | E | N |
| ATOM | 5615 | CA | LYS | E | 164 | −1.997 | 48.883 | 19.441 | 1.00 | 20.38 | E | C |
| ATOM | 5616 | CB | LYS | E | 164 | −3.054 | 49.917 | 19.064 | 1.00 | 18.13 | E | C |
| ATOM | 5617 | CG | LYS | E | 164 | −4.403 | 49.303 | 18.783 | 1.00 | 18.25 | E | C |
| ATOM | 5618 | CD | LYS | E | 164 | −5.420 | 50.356 | 18.418 | 1.00 | 21.07 | E | C |
| ATOM | 5619 | CE | LYS | E | 164 | −6.796 | 49.743 | 18.300 | 1.00 | 24.49 | E | C |
| ATOM | 5620 | NZ | LYS | E | 164 | −7.859 | 50.756 | 18.546 | 1.00 | 28.45 | E | N |
| ATOM | 5621 | C | LYS | E | 164 | −0.600 | 49.471 | 19.248 | 1.00 | 21.48 | E | C |
| ATOM | 5622 | O | LYS | E | 164 | 0.086 | 49.150 | 18.275 | 1.00 | 21.88 | E | O |
| ATOM | 5623 | N | TYR | E | 165 | −0.169 | 50.318 | 20.180 | 1.00 | 20.19 | E | N |
| ATOM | 5624 | CA | TYR | E | 165 | 1.155 | 50.921 | 20.073 | 1.00 | 20.44 | E | C |
| ATOM | 5625 | CB | TYR | E | 165 | 1.315 | 52.052 | 21.087 | 1.00 | 19.02 | E | C |
| ATOM | 5626 | CG | TYR | E | 165 | 0.785 | 53.372 | 20.595 | 1.00 | 18.38 | E | C |
| ATOM | 5627 | CD1 | TYR | E | 165 | 1.586 | 54.231 | 19.849 | 1.00 | 17.98 | E | C |
| ATOM | 5628 | CE1 | TYR | E | 165 | 1.092 | 55.443 | 19.373 | 1.00 | 17.49 | E | C |
| ATOM | 5629 | CD2 | TYR | E | 165 | −0.529 | 53.757 | 20.859 | 1.00 | 19.62 | E | C |
| ATOM | 5630 | CE2 | TYR | E | 165 | −1.033 | 54.966 | 20.390 | 1.00 | 19.13 | E | C |
| ATOM | 5631 | CZ | TYR | E | 165 | −0.215 | 55.800 | 19.647 | 1.00 | 18.93 | E | C |
| ATOM | 5632 | OH | TYR | E | 165 | −0.711 | 56.983 | 19.168 | 1.00 | 21.31 | E | O |
| ATOM | 5633 | C | TYR | E | 165 | 2.279 | 49.906 | 20.272 | 1.00 | 22.45 | E | C |
| ATOM | 5634 | O | TYR | E | 165 | 3.362 | 50.047 | 19.695 | 1.00 | 22.95 | E | O |
| ATOM | 5635 | N | LEU | E | 166 | 2.030 | 48.888 | 21.089 | 1.00 | 22.28 | E | N |
| ATOM | 5636 | CA | LEU | E | 166 | 3.045 | 47.872 | 21.342 | 1.00 | 22.43 | E | C |
| ATOM | 5637 | CB | LEU | E | 166 | 2.628 | 46.979 | 22.520 | 1.00 | 23.40 | E | C |
| ATOM | 5638 | CG | LEU | E | 166 | 2.617 | 47.596 | 23.936 | 1.00 | 24.01 | E | C |
| ATOM | 5639 | CD1 | LEU | E | 166 | 2.077 | 46.575 | 24.928 | 1.00 | 22.72 | E | C |
| ATOM | 5640 | CD2 | LEU | E | 166 | 4.016 | 48.042 | 24.346 | 1.00 | 18.55 | E | C |
| ATOM | 5641 | C | LEU | E | 166 | 3.253 | 47.032 | 20.085 | 1.00 | 22.85 | E | C |
| ATOM | 5642 | O | LEU | E | 166 | 4.386 | 46.732 | 19.712 | 1.00 | 22.81 | E | O |
| ATOM | 5643 | N | ARG | E | 167 | 2.158 | 46.657 | 19.431 | 1.00 | 22.45 | E | N |
| ATOM | 5644 | CA | ARG | E | 167 | 2.246 | 45.866 | 18.207 | 1.00 | 24.48 | E | C |
| ATOM | 5645 | CB | ARG | E | 167 | 0.845 | 45.517 | 17.696 | 1.00 | 22.66 | E | C |
| ATOM | 5646 | CG | ARG | E | 167 | 0.055 | 44.556 | 18.586 | 1.00 | 22.70 | E | C |
| ATOM | 5647 | CD | ARG | E | 167 | 0.800 | 43.258 | 18.848 | 1.00 | 22.57 | E | C |
| ATOM | 5648 | NE | ARG | E | 167 | 1.720 | 43.378 | 19.979 | 1.00 | 25.62 | E | N |
| ATOM | 5649 | CZ | ARG | E | 167 | 1.344 | 43.437 | 21.258 | 1.00 | 24.43 | E | C |
| ATOM | 5650 | NH1 | ARG | E | 167 | 0.059 | 43.384 | 21.583 | 1.00 | 23.43 | E | N |
| ATOM | 5651 | NH2 | ARG | E | 167 | 2.254 | 43.559 | 22.217 | 1.00 | 23.23 | E | N |
| ATOM | 5652 | C | ARG | E | 167 | 3.014 | 46.662 | 17.139 | 1.00 | 25.52 | E | C |
| ATOM | 5653 | O | ARG | E | 167 | 3.877 | 46.117 | 16.448 | 1.00 | 24.65 | E | O |
| ATOM | 5654 | N | SER | E | 168 | 2.707 | 47.954 | 17.025 | 1.00 | 26.68 | E | N |
| ATOM | 5655 | CA | SER | E | 168 | 3.365 | 48.832 | 16.057 | 1.00 | 27.61 | E | C |
| ATOM | 5656 | CB | SER | E | 168 | 2.808 | 50.250 | 16.146 | 1.00 | 28.14 | E | C |
| ATOM | 5657 | OG | SER | E | 168 | 1.405 | 50.227 | 16.316 | 1.00 | 34.03 | E | O |
| ATOM | 5658 | C | SER | E | 168 | 4.857 | 48.901 | 16.292 | 1.00 | 27.75 | E | C |
| ATOM | 5659 | O | SER | E | 168 | 5.649 | 48.791 | 15.360 | 1.00 | 29.12 | E | O |
| ATOM | 5660 | N | ILE | E | 169 | 5.239 | 49.106 | 17.543 | 1.00 | 27.78 | E | N |
| ATOM | 5661 | CA | ILE | E | 169 | 6.646 | 49.200 | 17.886 | 1.00 | 28.75 | E | C |
| ATOM | 5662 | CB | ILE | E | 169 | 6.828 | 49.494 | 19.396 | 1.00 | 27.48 | E | C |
| ATOM | 5663 | CG2 | ILE | E | 169 | 8.294 | 49.376 | 19.782 | 1.00 | 25.04 | E | C |
| ATOM | 5664 | CG1 | ILE | E | 169 | 6.282 | 50.894 | 19.711 | 1.00 | 28.04 | E | C |
| ATOM | 5665 | CD1 | ILE | E | 169 | 6.586 | 51.393 | 21.103 | 1.00 | 26.12 | E | C |
| ATOM | 5666 | C | ILE | E | 169 | 7.347 | 47.899 | 17.531 | 1.00 | 30.05 | E | C |
| ATOM | 5667 | O | ILE | E | 169 | 8.522 | 47.893 | 17.158 | 1.00 | 29.64 | E | O |
| ATOM | 5668 | N | GLU | E | 170 | 6.606 | 46.803 | 17.637 | 1.00 | 31.99 | E | N |
| ATOM | 5669 | CA | GLU | E | 170 | 7.128 | 45.474 | 17.355 | 1.00 | 34.62 | E | C |
| ATOM | 5670 | CB | GLU | E | 170 | 6.196 | 44.416 | 17.937 | 1.00 | 34.60 | E | C |
| ATOM | 5671 | CG | GLU | E | 170 | 6.481 | 44.068 | 19.371 | 1.00 | 36.86 | E | C |
| ATOM | 5672 | CD | GLU | E | 170 | 5.270 | 43.488 | 20.068 | 1.00 | 38.91 | E | C |
| ATOM | 5673 | OE1 | GLU | E | 170 | 5.149 | 43.668 | 21.303 | 1.00 | 39.41 | E | O |
| ATOM | 5674 | OE2 | GLU | E | 170 | 4.439 | 42.856 | 19.376 | 1.00 | 40.35 | E | O |
| ATOM | 5675 | C | GLU | E | 170 | 7.295 | 45.217 | 15.866 | 1.00 | 36.24 | E | C |
| ATOM | 5676 | O | GLU | E | 170 | 8.178 | 44.462 | 15.454 | 1.00 | 35.96 | E | O |
| ATOM | 5677 | N | GLY | E | 171 | 6.439 | 45.838 | 15.063 | 1.00 | 37.89 | E | N |
| ATOM | 5678 | CA | GLY | E | 171 | 6.511 | 45.647 | 13.630 | 1.00 | 40.37 | E | C |
| ATOM | 5679 | C | GLY | E | 171 | 5.444 | 44.683 | 13.155 | 1.00 | 42.99 | E | C |
| ATOM | 5680 | O | GLY | E | 171 | 5.498 | 44.194 | 12.026 | 1.00 | 44.19 | E | O |
| ATOM | 5681 | N | THR | E | 172 | 4.473 | 44.403 | 14.020 | 1.00 | 44.67 | E | N |
| ATOM | 5682 | CA | THR | E | 172 | 3.386 | 43.499 | 13.671 | 1.00 | 46.09 | E | C |
| ATOM | 5683 | CB | THR | E | 172 | 3.260 | 42.343 | 14.688 | 1.00 | 46.19 | E | C |
| ATOM | 5684 | OG1 | THR | E | 172 | 2.039 | 42.484 | 15.423 | 1.00 | 47.97 | E | O |
| ATOM | 5685 | CG2 | THR | E | 172 | 4.436 | 42.340 | 15.651 | 1.00 | 45.35 | E | C |
| ATOM | 5686 | C | THR | E | 172 | 2.068 | 44.265 | 13.611 | 1.00 | 47.33 | E | C |
| ATOM | 5687 | O | THR | E | 172 | 1.969 | 45.389 | 14.106 | 1.00 | 46.28 | E | O |
| ATOM | 5688 | N | ALA | E | 173 | 1.061 | 43.659 | 12.990 | 1.00 | 50.12 | E | N |
| ATOM | 5689 | CA | ALA | E | 173 | −0.249 | 44.289 | 12.857 | 1.00 | 52.01 | E | C |
| ATOM | 5690 | CB | ALA | E | 173 | −0.928 | 43.823 | 11.571 | 1.00 | 52.13 | E | C |
| ATOM | 5691 | C | ALA | E | 173 | −1.113 | 43.948 | 14.063 | 1.00 | 52.83 | E | C |
| ATOM | 5692 | O | ALA | E | 173 | −1.064 | 42.828 | 14.581 | 1.00 | 53.66 | E | O |
| ATOM | 5693 | N | TRP | E | 174 | −1.906 | 44.915 | 14.509 | 1.00 | 53.07 | E | N |
| ATOM | 5694 | CA | TRP | E | 174 | −2.762 | 44.702 | 15.666 | 1.00 | 53.29 | E | C |
| ATOM | 5695 | CB | TRP | E | 174 | −3.244 | 46.040 | 16.231 | 1.00 | 51.56 | E | C |
| ATOM | 5696 | CG | TRP | E | 174 | −4.091 | 45.885 | 17.461 | 1.00 | 49.61 | E | C |
| ATOM | 5697 | CD2 | TRP | E | 174 | −5.504 | 46.090 | 17.557 | 1.00 | 48.32 | E | C |
| ATOM | 5698 | CE2 | TRP | E | 174 | −5.878 | 45.799 | 18.888 | 1.00 | 47.77 | E | C |
| ATOM | 5699 | CE3 | TRP | E | 174 | −6.492 | 46.489 | 16.645 | 1.00 | 48.46 | E | C |
| ATOM | 5700 | CD1 | TRP | E | 174 | −3.676 | 45.492 | 18.703 | 1.00 | 48.12 | E | C |
| ATOM | 5701 | NE1 | TRP | E | 174 | −4.744 | 45.439 | 19.565 | 1.00 | 46.28 | E | N |
| ATOM | 5702 | CZ2 | TRP | E | 174 | −7.201 | 45.898 | 19.332 | 1.00 | 48.44 | E | C |
| ATOM | 5703 | CZ3 | TRP | E | 174 | −7.811 | 46.586 | 17.087 | 1.00 | 48.86 | E | C |
| ATOM | 5704 | CH2 | TRP | E | 174 | −8.151 | 46.291 | 18.421 | 1.00 | 48.77 | E | C |
| ATOM | 5705 | C | TRP | E | 174 | −3.958 | 43.815 | 15.353 | 1.00 | 54.21 | E | C |
| ATOM | 5706 | O | TRP | E | 174 | −4.714 | 44.075 | 14.417 | 1.00 | 54.68 | E | O |
| ATOM | 5707 | N | LYS | E | 175 | −4.117 | 42.770 | 16.160 | 1.00 | 55.53 | E | N |
| ATOM | 5708 | CA | LYS | E | 175 | −5.208 | 41.815 | 16.016 | 1.00 | 57.49 | E | C |
| ATOM | 5709 | CB | LYS | E | 175 | −4.788 | 40.465 | 16.596 | 1.00 | 59.83 | E | C |
| ATOM | 5710 | CG | LYS | E | 175 | −3.847 | 40.575 | 17.790 | 1.00 | 61.93 | E | C |
| ATOM | 5711 | CD | LYS | E | 175 | −3.291 | 39.210 | 18.184 | 1.00 | 63.98 | E | C |
| ATOM | 5712 | CE | LYS | E | 175 | −2.620 | 38.511 | 16.999 | 1.00 | 65.27 | E | C |
| ATOM | 5713 | NZ | LYS | E | 175 | −3.447 | 37.386 | 16.456 | 1.00 | 65.04 | E | N |
| ATOM | 5714 | C | LYS | E | 175 | −6.475 | 42.293 | 16.726 | 1.00 | 58.41 | E | C |
| ATOM | 5715 | O | LYS | E | 175 | −6.994 | 43.370 | 16.433 | 1.00 | 59.44 | E | O |
| ATOM | 5716 | N | ALA | E | 176 | −6.965 | 41.475 | 17.657 | 1.00 | 58.67 | E | N |
| ATOM | 5717 | CA | ALA | E | 176 | −8.167 | 41.780 | 18.430 | 1.00 | 58.43 | E | C |
| ATOM | 5718 | CB | ALA | E | 176 | −9.294 | 42.241 | 17.507 | 1.00 | 57.51 | E | C |
| ATOM | 5719 | C | ALA | E | 176 | −8.605 | 40.542 | 19.208 | 1.00 | 58.92 | E | C |
| ATOM | 5720 | O | ALA | E | 176 | −9.758 | 40.442 | 19.635 | 1.00 | 59.67 | E | O |
| ATOM | 5721 | N | ASN | E | 177 | −7.680 | 39.600 | 19.385 | 1.00 | 58.92 | E | N |
| ATOM | 5722 | CA | ASN | E | 177 | −7.956 | 38.357 | 20.105 | 1.00 | 58.41 | E | C |
| ATOM | 5723 | CB | ASN | E | 177 | −6.639 | 37.656 | 20.461 | 1.00 | 60.09 | E | C |
| ATOM | 5724 | CG | ASN | E | 177 | −5.796 | 38.456 | 21.449 | 1.00 | 61.89 | E | C |
| ATOM | 5725 | OD1 | ASN | E | 177 | −5.858 | 39.687 | 21.484 | 1.00 | 62.50 | E | O |
| ATOM | 5726 | ND2 | ASN | E | 177 | −5.004 | 37.756 | 22.258 | 1.00 | 62.24 | E | N |
| ATOM | 5727 | C | ASN | E | 177 | −8.768 | 38.597 | 21.378 | 1.00 | 57.19 | E | C |
| ATOM | 5728 | O | ASN | E | 177 | −8.350 | 39.349 | 22.259 | 1.00 | 56.67 | E | O |
| ATOM | 5729 | N | GLU | E | 178 | −9.930 | 37.956 | 21.467 | 1.00 | 56.42 | E | N |
| ATOM | 5730 | CA | GLU | E | 178 | −10.789 | 38.103 | 22.638 | 1.00 | 56.05 | E | C |
| ATOM | 5731 | CB | GLU | E | 178 | −12.208 | 38.486 | 22.202 | 1.00 | 57.27 | E | C |
| ATOM | 5732 | CG | GLU | E | 178 | −12.332 | 39.913 | 21.676 | 1.00 | 59.96 | E | C |
| ATOM | 5733 | CD | GLU | E | 178 | −12.020 | 40.972 | 22.732 | 1.00 | 62.07 | E | C |
| ATOM | 5734 | OE1 | GLU | E | 178 | −10.877 | 41.005 | 23.237 | 1.00 | 62.23 | E | O |
| ATOM | 5735 | OE2 | GLU | E | 178 | −12.919 | 41.779 | 23.054 | 1.00 | 63.29 | E | O |
| ATOM | 5736 | C | GLU | E | 178 | −10.820 | 36.822 | 23.482 | 1.00 | 54.50 | E | C |
| ATOM | 5737 | O | GLU | E | 178 | −11.669 | 36.662 | 24.363 | 1.00 | 54.35 | E | O |
| ATOM | 5738 | N | SER | E | 179 | −9.878 | 35.920 | 23.212 | 1.00 | 52.49 | E | N |
| ATOM | 5739 | CA | SER | E | 179 | −9.782 | 34.650 | 23.929 | 1.00 | 49.77 | E | C |
| ATOM | 5740 | CB | SER | E | 179 | −8.819 | 33.706 | 23.199 | 1.00 | 48.06 | E | C |
| ATOM | 5741 | OG | SER | E | 179 | −7.990 | 34.418 | 22.298 | 1.00 | 49.07 | E | O |
| ATOM | 5742 | C | SER | E | 179 | −9.324 | 34.812 | 25.381 | 1.00 | 47.95 | E | C |
| ATOM | 5743 | O | SER | E | 179 | −9.715 | 34.024 | 26.247 | 1.00 | 47.44 | E | O |
| ATOM | 5744 | N | SER | E | 180 | −8.498 | 35.826 | 25.642 | 1.00 | 45.39 | E | N |
| ATOM | 5745 | CA | SER | E | 180 | −7.984 | 36.079 | 26.989 | 1.00 | 43.96 | E | C |
| ATOM | 5746 | CB | SER | E | 180 | −6.533 | 36.553 | 26.918 | 1.00 | 44.71 | E | C |
| ATOM | 5747 | OG | SER | E | 180 | −5.897 | 36.062 | 25.751 | 1.00 | 45.72 | E | O |
| ATOM | 5748 | C | SER | E | 180 | −8.823 | 37.112 | 27.729 | 1.00 | 42.80 | E | C |
| ATOM | 5749 | O | SER | E | 180 | −8.373 | 37.725 | 28.694 | 1.00 | 42.22 | E | O |
| ATOM | 5750 | N | TYR | E | 181 | −10.049 | 37.296 | 27.261 | 1.00 | 42.81 | E | N |
| ATOM | 5751 | CA | TYR | E | 181 | −10.983 | 38.242 | 27.854 | 1.00 | 42.86 | E | C |
| ATOM | 5752 | CB | TYR | E | 181 | −12.088 | 38.556 | 26.847 | 1.00 | 47.36 | E | C |
| ATOM | 5753 | CG | TYR | E | 181 | −12.296 | 40.024 | 26.575 | 1.00 | 51.50 | E | C |
| ATOM | 5754 | CD1 | TYR | E | 181 | −13.537 | 40.622 | 26.798 | 1.00 | 54.46 | E | C |
| ATOM | 5755 | CE1 | TYR | E | 181 | −13.747 | 41.978 | 26.531 | 1.00 | 57.51 | E | C |
| ATOM | 5756 | CD2 | TYR | E | 181 | −11.261 | 40.814 | 26.077 | 1.00 | 54.04 | E | C |
| ATOM | 5757 | CE2 | TYR | E | 181 | −11.456 | 42.172 | 25.805 | 1.00 | 57.05 | E | C |
| ATOM | 5758 | CZ | TYR | E | 181 | −12.702 | 42.749 | 26.034 | 1.00 | 59.03 | E | C |
| ATOM | 5759 | OH | TYR | E | 181 | −12.903 | 44.091 | 25.770 | 1.00 | 60.79 | E | O |
| ATOM | 5760 | C | TYR | E | 181 | −11.605 | 37.639 | 29.113 | 1.00 | 40.86 | E | C |
| ATOM | 5761 | O | TYR | E | 181 | −11.990 | 36.467 | 29.120 | 1.00 | 40.41 | E | O |
| ATOM | 5762 | N | PRO | E | 182 | −11.698 | 38.426 | 30.199 | 1.00 | 38.87 | E | N |
| ATOM | 5763 | CD | PRO | E | 182 | −11.250 | 39.819 | 30.361 | 1.00 | 37.17 | E | C |
| ATOM | 5764 | CA | PRO | E | 182 | −12.295 | 37.890 | 31.430 | 1.00 | 37.69 | E | C |
| ATOM | 5765 | CB | PRO | E | 182 | −12.200 | 39.052 | 32.423 | 1.00 | 36.28 | E | C |
| ATOM | 5766 | CG | PRO | E | 182 | −11.975 | 40.266 | 31.590 | 1.00 | 36.10 | E | C |
| ATOM | 5767 | C | PRO | E | 182 | −13.740 | 37.466 | 31.168 | 1.00 | 37.57 | E | C |
| ATOM | 5768 | O | PRO | E | 182 | −14.398 | 38.029 | 30.291 | 1.00 | 38.90 | E | O |
| ATOM | 5769 | N | VAL | E | 183 | −14.228 | 36.476 | 31.914 | 1.00 | 35.54 | E | N |
| ATOM | 5770 | CA | VAL | E | 183 | −15.594 | 35.992 | 31.736 | 1.00 | 32.51 | E | C |
| ATOM | 5771 | CB | VAL | E | 183 | −15.611 | 34.475 | 31.481 | 1.00 | 31.67 | E | C |
| ATOM | 5772 | CG1 | VAL | E | 183 | −16.998 | 34.026 | 31.081 | 1.00 | 31.20 | E | C |
| ATOM | 5773 | CG2 | VAL | E | 183 | −14.621 | 34.127 | 30.403 | 1.00 | 32.35 | E | C |
| ATOM | 5774 | C | VAL | E | 183 | −16.492 | 36.296 | 32.934 | 1.00 | 32.85 | E | C |
| ATOM | 5775 | O | VAL | E | 183 | −16.456 | 35.595 | 33.945 | 1.00 | 32.11 | E | O |
| ATOM | 5776 | N | PHE | E | 184 | −17.295 | 37.349 | 32.814 | 1.00 | 34.50 | E | N |
| ATOM | 5777 | CA | PHE | E | 184 | −18.218 | 37.737 | 33.874 | 1.00 | 36.00 | E | C |
| ATOM | 5778 | CB | PHE | E | 184 | −18.546 | 39.226 | 33.777 | 1.00 | 39.46 | E | C |
| ATOM | 5779 | CG | PHE | E | 184 | −17.380 | 40.123 | 34.079 | 1.00 | 43.73 | E | C |
| ATOM | 5780 | CD1 | PHE | E | 184 | −17.358 | 40.888 | 35.240 | 1.00 | 45.41 | E | C |
| ATOM | 5781 | CD2 | PHE | E | 184 | −16.299 | 40.205 | 33.200 | 1.00 | 46.01 | E | C |
| ATOM | 5782 | CE1 | PHE | E | 184 | −16.275 | 41.725 | 35.526 | 1.00 | 47.18 | E | C |
| ATOM | 5783 | CE2 | PHE | E | 184 | −15.211 | 41.038 | 33.477 | 1.00 | 46.38 | E | C |
| ATOM | 5784 | CZ | PHE | E | 184 | −15.201 | 41.800 | 34.643 | 1.00 | 46.30 | E | C |
| ATOM | 5785 | C | PHE | E | 184 | −19.485 | 36.920 | 33.689 | 1.00 | 35.61 | E | C |
| ATOM | 5786 | O | PHE | E | 184 | −19.936 | 36.727 | 32.562 | 1.00 | 35.86 | E | O |
| ATOM | 5787 | N | THR | E | 185 | −20.064 | 36.425 | 34.776 | 1.00 | 35.24 | E | N |
| ATOM | 5788 | CA | THR | E | 185 | −21.275 | 35.637 | 34.618 | 1.00 | 35.33 | E | C |
| ATOM | 5789 | CB | THR | E | 185 | −21.689 | 34.930 | 35.947 | 1.00 | 34.07 | E | C |
| ATOM | 5790 | OG1 | THR | E | 185 | −23.007 | 35.339 | 36.329 | 1.00 | 33.36 | E | O |
| ATOM | 5791 | CG2 | THR | E | 185 | −20.699 | 35.234 | 37.047 | 1.00 | 32.86 | E | C |
| ATOM | 5792 | C | THR | E | 185 | −22.389 | 36.542 | 34.084 | 1.00 | 36.12 | E | C |
| ATOM | 5793 | O | THR | E | 185 | −22.550 | 37.684 | 34.525 | 1.00 | 36.40 | E | O |
| ATOM | 5794 | N | PRO | E | 186 | −23.150 | 36.048 | 33.094 | 1.00 | 36.44 | E | N |
| ATOM | 5795 | CD | PRO | E | 186 | −22.993 | 34.713 | 32.492 | 1.00 | 35.65 | E | C |
| ATOM | 5796 | CA | PRO | E | 186 | −24.252 | 36.790 | 32.471 | 1.00 | 36.68 | E | C |
| ATOM | 5797 | CB | PRO | E | 186 | −24.876 | 35.776 | 31.504 | 1.00 | 36.41 | E | C |
| ATOM | 5798 | CG | PRO | E | 186 | −24.347 | 34.448 | 31.929 | 1.00 | 36.42 | E | C |
| ATOM | 5799 | C | PRO | E | 186 | −25.282 | 37.349 | 33.434 | 1.00 | 36.70 | E | C |
| ATOM | 5800 | O | PRO | E | 186 | −25.530 | 36.775 | 34.493 | 1.00 | 38.41 | E | O |
| ATOM | 5801 | N | ALA | E | 187 | −25.873 | 38.480 | 33.063 | 1.00 | 36.25 | E | N |
| ATOM | 5802 | CA | ALA | E | 187 | −26.906 | 39.093 | 33.883 | 1.00 | 37.28 | E | C |
| ATOM | 5803 | CB | ALA | E | 187 | −27.349 | 40.415 | 33.270 | 1.00 | 35.25 | E | C |
| ATOM | 5804 | C | ALA | E | 187 | −28.069 | 38.106 | 33.903 | 1.00 | 38.90 | E | C |
| ATOM | 5805 | O | ALA | E | 187 | −28.267 | 37.364 | 32.941 | 1.00 | 38.90 | E | O |
| ATOM | 5806 | N | LEU | E | 188 | −28.827 | 38.066 | 34.992 | 1.00 | 40.41 | E | N |
| ATOM | 5807 | CA | LEU | E | 188 | −29.947 | 37.147 | 35.026 | 1.00 | 43.04 | E | C |
| ATOM | 5808 | CB | LEU | E | 188 | −30.199 | 36.621 | 36.448 | 1.00 | 42.93 | E | C |
| ATOM | 5809 | CG | LEU | E | 188 | −29.977 | 37.486 | 37.684 | 1.00 | 42.59 | E | C |
| ATOM | 5810 | CD1 | LEU | E | 188 | −31.271 | 37.552 | 38.493 | 1.00 | 43.17 | E | C |
| ATOM | 5811 | CD2 | LEU | E | 188 | −28.857 | 36.886 | 38.521 | 1.00 | 40.69 | E | C |
| ATOM | 5812 | C | LEU | E | 188 | −31.184 | 37.846 | 34.483 | 1.00 | 43.69 | E | C |
| ATOM | 5813 | O | LEU | E | 188 | −31.378 | 39.038 | 34.706 | 1.00 | 43.14 | E | O |
| ATOM | 5814 | N | LYS | E | 189 | −32.002 | 37.101 | 33.747 | 1.00 | 45.47 | E | N |
| ATOM | 5815 | CA | LYS | E | 189 | −33.221 | 37.644 | 33.170 | 1.00 | 47.67 | E | C |
| ATOM | 5816 | CB | LYS | E | 189 | −33.995 | 36.538 | 32.451 | 1.00 | 46.70 | E | C |
| ATOM | 5817 | CG | LYS | E | 189 | −33.125 | 35.656 | 31.577 | 1.00 | 46.86 | E | C |
| ATOM | 5818 | CD | LYS | E | 189 | −33.084 | 36.165 | 30.143 | 1.00 | 48.28 | E | C |
| ATOM | 5819 | CE | LYS | E | 189 | −31.674 | 36.562 | 29.721 | 1.00 | 49.33 | E | C |
| ATOM | 5820 | NZ | LYS | E | 189 | −30.773 | 35.384 | 29.545 | 1.00 | 49.46 | E | N |
| ATOM | 5821 | C | LYS | E | 189 | −34.080 | 38.262 | 34.267 | 1.00 | 49.84 | E | C |
| ATOM | 5822 | O | LYS | E | 189 | −33.987 | 37.877 | 35.435 | 1.00 | 50.07 | E | O |
| ATOM | 5823 | N | LYS | E | 190 | −34.904 | 39.234 | 33.895 | 1.00 | 52.41 | E | N |
| ATOM | 5824 | CA | LYS | E | 190 | −35.779 | 39.889 | 34.860 | 1.00 | 55.23 | E | C |
| ATOM | 5825 | CB | LYS | E | 190 | −36.726 | 40.858 | 34.145 | 1.00 | 58.03 | E | C |
| ATOM | 5826 | CG | LYS | E | 190 | −37.754 | 41.523 | 35.051 | 1.00 | 60.89 | E | C |
| ATOM | 5827 | CD | LYS | E | 190 | −39.180 | 41.209 | 34.602 | 1.00 | 64.03 | E | C |
| ATOM | 5828 | CE | LYS | E | 190 | −39.406 | 41.554 | 33.128 | 1.00 | 65.14 | E | C |
| ATOM | 5829 | NZ | LYS | E | 190 | −39.956 | 40.399 | 32.355 | 1.00 | 65.07 | E | N |
| ATOM | 5830 | C | LYS | E | 190 | −36.578 | 38.817 | 35.591 | 1.00 | 55.17 | E | C |
| ATOM | 5831 | O | LYS | E | 190 | −37.234 | 37.980 | 34.967 | 1.00 | 56.41 | E | O |
| ATOM | 5832 | N | GLY | E | 191 | −36.515 | 38.835 | 36.915 | 1.00 | 54.97 | E | N |
| ATOM | 5833 | CA | GLY | E | 191 | −37.235 | 37.837 | 37.678 | 1.00 | 55.27 | E | C |
| ATOM | 5834 | C | GLY | E | 191 | −36.760 | 36.442 | 37.312 | 1.00 | 54.97 | E | C |
| ATOM | 5835 | O | GLY | E | 191 | −37.428 | 35.709 | 36.565 | 1.00 | 56.34 | E | O |
| ATOM | 5836 | N | GLU | E | 192 | −35.587 | 36.085 | 37.824 | 1.00 | 51.59 | E | N |
| ATOM | 5837 | CA | GLU | E | 192 | −35.003 | 34.776 | 37.578 | 1.00 | 48.47 | E | C |
| ATOM | 5838 | CB | GLU | E | 192 | −33.977 | 34.841 | 36.442 | 1.00 | 46.68 | E | C |
| ATOM | 5839 | CG | GLU | E | 192 | −33.426 | 33.483 | 36.035 | 1.00 | 44.96 | E | C |
| ATOM | 5840 | CD | GLU | E | 192 | −32.148 | 33.582 | 35.223 | 1.00 | 42.84 | E | C |
| ATOM | 5841 | OE1 | GLU | E | 192 | −31.514 | 32.537 | 34.977 | 1.00 | 43.39 | E | O |
| ATOM | 5842 | OE2 | GLU | E | 192 | −31.775 | 34.701 | 34.826 | 1.00 | 41.87 | E | O |
| ATOM | 5843 | C | GLU | E | 192 | −34.326 | 34.338 | 38.865 | 1.00 | 46.59 | E | C |
| ATOM | 5844 | O | GLU | E | 192 | −33.853 | 35.170 | 39.631 | 1.00 | 46.45 | E | O |
| ATOM | 5845 | N | ASP | E | 193 | −34.293 | 33.032 | 39.104 | 1.00 | 44.63 | E | N |
| ATOM | 5846 | CA | ASP | E | 193 | −33.674 | 32.482 | 40.302 | 1.00 | 40.04 | E | C |
| ATOM | 5847 | CB | ASP | E | 193 | −34.000 | 30.989 | 40.413 | 1.00 | 41.79 | E | C |
| ATOM | 5848 | CG | ASP | E | 193 | −33.675 | 30.421 | 41.777 | 1.00 | 43.34 | E | C |
| ATOM | 5849 | OD1 | ASP | E | 193 | −33.104 | 29.313 | 41.835 | 1.00 | 46.70 | E | O |
| ATOM | 5850 | OD2 | ASP | E | 193 | −33.988 | 31.076 | 42.792 | 1.00 | 43.13 | E | O |
| ATOM | 5851 | C | ASP | E | 193 | −32.161 | 32.686 | 40.268 | 1.00 | 37.21 | E | C |
| ATOM | 5852 | O | ASP | E | 193 | −31.464 | 32.135 | 39.415 | 1.00 | 36.66 | E | O |
| ATOM | 5853 | N | PRO | E | 194 | −31.630 | 33.485 | 41.203 | 1.00 | 34.25 | E | N |
| ATOM | 5854 | CD | PRO | E | 194 | −32.331 | 34.200 | 42.277 | 1.00 | 33.22 | E | C |
| ATOM | 5855 | CA | PRO | E | 194 | −30.188 | 33.733 | 41.239 | 1.00 | 32.51 | E | C |
| ATOM | 5856 | CB | PRO | E | 194 | −30.041 | 34.942 | 42.167 | 1.00 | 31.98 | E | C |
| ATOM | 5857 | CG | PRO | E | 194 | −31.432 | 35.359 | 42.538 | 1.00 | 31.80 | E | C |
| ATOM | 5858 | C | PRO | E | 194 | −29.422 | 32.535 | 41.762 | 1.00 | 31.18 | E | C |
| ATOM | 5859 | O | PRO | E | 194 | −28.194 | 32.486 | 41.675 | 1.00 | 31.44 | E | O |
| ATOM | 5860 | N | PHE | E | 195 | −30.152 | 31.563 | 42.294 | 1.00 | 30.77 | E | N |
| ATOM | 5861 | CA | PHE | E | 195 | −29.528 | 30.373 | 42.857 | 1.00 | 31.94 | E | C |
| ATOM | 5862 | CB | PHE | E | 195 | −29.890 | 30.280 | 44.336 | 1.00 | 30.48 | E | C |
| ATOM | 5863 | CG | PHE | E | 195 | −29.738 | 31.587 | 45.072 | 1.00 | 30.35 | E | C |
| ATOM | 5864 | CD1 | PHE | E | 195 | −28.482 | 32.023 | 45.495 | 1.00 | 28.19 | E | C |
| ATOM | 5865 | CD2 | PHE | E | 195 | −30.842 | 32.398 | 45.313 | 1.00 | 28.04 | E | C |
| ATOM | 5866 | CE1 | PHE | E | 195 | −28.336 | 33.245 | 46.144 | 1.00 | 24.75 | E | C |
| ATOM | 5867 | CE2 | PHE | E | 195 | −30.700 | 33.621 | 45.961 | 1.00 | 26.74 | E | C |
| ATOM | 5868 | CZ | PHE | E | 195 | −29.445 | 34.042 | 46.376 | 1.00 | 24.20 | E | C |
| ATOM | 5869 | C | PHE | E | 195 | −29.863 | 29.064 | 42.150 | 1.00 | 33.75 | E | C |
| ATOM | 5870 | O | PHE | E | 195 | −29.834 | 28.001 | 42.768 | 1.00 | 32.88 | E | O |
| ATOM | 5871 | N | ARG | E | 196 | −30.163 | 29.150 | 40.855 | 1.00 | 35.26 | E | N |
| ATOM | 5872 | CA | ARG | E | 196 | −30.500 | 27.979 | 40.049 | 1.00 | 36.83 | E | C |
| ATOM | 5873 | CB | ARG | E | 196 | −30.759 | 28.387 | 38.597 | 1.00 | 37.41 | E | C |
| ATOM | 5874 | CG | ARG | E | 196 | −31.916 | 29.340 | 38.420 | 1.00 | 38.95 | E | C |
| ATOM | 5875 | CD | ARG | E | 196 | −32.164 | 29.643 | 36.956 | 1.00 | 42.24 | E | C |
| ATOM | 5876 | NE | ARG | E | 196 | −32.257 | 28.428 | 36.156 | 1.00 | 44.68 | E | N |
| ATOM | 5877 | CZ | ARG | E | 196 | −32.769 | 28.378 | 34.932 | 1.00 | 44.96 | E | C |
| ATOM | 5878 | NH1 | ARG | E | 196 | −33.238 | 29.479 | 34.361 | 1.00 | 44.01 | E | N |
| ATOM | 5879 | NH2 | ARG | E | 196 | −32.810 | 27.224 | 34.279 | 1.00 | 45.80 | E | N |
| ATOM | 5880 | C | ARG | E | 196 | −29.376 | 26.955 | 40.088 | 1.00 | 37.24 | E | C |
| ATOM | 5881 | O | ARG | E | 196 | −28.200 | 27.308 | 40.065 | 1.00 | 36.09 | E | O |
| ATOM | 5882 | N | THR | E | 197 | −29.742 | 25.680 | 40.129 | 1.00 | 38.22 | E | N |
| ATOM | 5883 | CA | THR | E | 197 | −28.746 | 24.625 | 40.180 | 1.00 | 39.57 | E | C |
| ATOM | 5884 | CB | THR | E | 197 | −28.734 | 23.980 | 41.581 | 1.00 | 40.19 | E | C |
| ATOM | 5885 | OG1 | THR | E | 197 | −27.491 | 23.299 | 41.785 | 1.00 | 41.95 | E | O |
| ATOM | 5886 | CG2 | THR | E | 197 | −29.894 | 23.005 | 41.737 | 1.00 | 40.40 | E | C |
| ATOM | 5887 | C | THR | E | 197 | −28.985 | 23.551 | 39.115 | 1.00 | 39.53 | E | C |
| ATOM | 5888 | O | THR | E | 197 | −28.422 | 22.458 | 39.185 | 1.00 | 39.35 | E | O |
| ATOM | 5889 | N | ASP | E | 198 | −29.808 | 23.876 | 38.122 | 1.00 | 39.92 | E | N |
| ATOM | 5890 | CA | ASP | E | 198 | −30.118 | 22.936 | 37.055 | 1.00 | 40.72 | E | C |
| ATOM | 5891 | CB | ASP | E | 198 | −31.589 | 23.065 | 36.654 | 1.00 | 40.28 | E | C |
| ATOM | 5892 | CG | ASP | E | 198 | −31.958 | 24.465 | 36.196 | 1.00 | 41.08 | E | C |
| ATOM | 5893 | OD1 | ASP | E | 198 | −31.953 | 25.389 | 37.035 | 1.00 | 42.03 | E | O |
| ATOM | 5894 | OD2 | ASP | E | 198 | −32.265 | 24.643 | 34.997 | 1.00 | 40.98 | E | O |
| ATOM | 5895 | C | ASP | E | 198 | −29.239 | 23.092 | 35.818 | 1.00 | 40.89 | E | C |
| ATOM | 5896 | O | ASP | E | 198 | −29.265 | 22.249 | 34.923 | 1.00 | 42.76 | E | O |
| ATOM | 5897 | N | ASN | E | 199 | −28.449 | 24.156 | 35.772 | 1.00 | 40.44 | E | N |
| ATOM | 5898 | CA | ASN | E | 199 | −27.588 | 24.403 | 34.623 | 1.00 | 40.54 | E | C |
| ATOM | 5899 | CB | ASN | E | 199 | −27.840 | 25.815 | 34.101 | 1.00 | 43.90 | E | C |
| ATOM | 5900 | CG | ASN | E | 199 | −28.057 | 26.818 | 35.227 | 1.00 | 49.09 | E | C |
| ATOM | 5901 | OD1 | ASN | E | 199 | −28.815 | 27.781 | 35.081 | 1.00 | 49.41 | E | O |
| ATOM | 5902 | ND2 | ASN | E | 199 | −27.390 | 26.594 | 36.361 | 1.00 | 50.43 | E | N |
| ATOM | 5903 | C | ASN | E | 199 | −26.104 | 24.227 | 34.935 | 1.00 | 39.00 | E | C |
| ATOM | 5904 | O | ASN | E | 199 | −25.250 | 24.771 | 34.238 | 1.00 | 39.30 | E | O |
| ATOM | 5905 | N | LEU | E | 200 | −25.798 | 23.463 | 35.977 | 1.00 | 37.27 | E | N |
| ATOM | 5906 | CA | LEU | E | 200 | −24.414 | 23.228 | 36.368 | 1.00 | 35.44 | E | C |
| ATOM | 5907 | CB | LEU | E | 200 | −24.336 | 22.835 | 37.850 | 1.00 | 35.08 | E | C |
| ATOM | 5908 | CG | LEU | E | 200 | −24.554 | 23.898 | 38.928 | 1.00 | 34.90 | E | C |
| ATOM | 5909 | CD1 | LEU | E | 200 | −24.395 | 23.247 | 40.287 | 1.00 | 34.35 | E | C |
| ATOM | 5910 | CD2 | LEU | E | 200 | −23.555 | 25.034 | 38.764 | 1.00 | 33.63 | E | C |
| ATOM | 5911 | C | LEU | E | 200 | −23.769 | 22.122 | 35.534 | 1.00 | 35.08 | E | C |
| ATOM | 5912 | O | LEU | E | 200 | −24.409 | 21.123 | 35.213 | 1.00 | 34.95 | E | O |
| ATOM | 5913 | N | PRO | E | 201 | −22.487 | 22.292 | 35.172 | 1.00 | 34.05 | E | N |
| ATOM | 5914 | CD | PRO | E | 201 | −21.659 | 23.469 | 35.479 | 1.00 | 32.67 | E | C |
| ATOM | 5915 | CA | PRO | E | 201 | −21.752 | 21.303 | 34.379 | 1.00 | 34.81 | E | C |
| ATOM | 5916 | CB | PRO | E | 201 | −20.366 | 21.932 | 34.204 | 1.00 | 33.12 | E | C |
| ATOM | 5917 | CG | PRO | E | 201 | −20.562 | 23.372 | 34.476 | 1.00 | 33.08 | E | C |
| ATOM | 5918 | C | PRO | E | 201 | −21.668 | 19.937 | 35.069 | 1.00 | 36.26 | E | C |
| ATOM | 5919 | O | PRO | E | 201 | −22.121 | 19.772 | 36.203 | 1.00 | 36.84 | E | O |
| ATOM | 5920 | N | GLU | E | 202 | −21.079 | 18.967 | 34.381 | 1.00 | 37.44 | E | N |
| ATOM | 5921 | CA | GLU | E | 202 | −20.928 | 17.624 | 34.924 | 1.00 | 40.87 | E | C |
| ATOM | 5922 | CB | GLU | E | 202 | −21.019 | 16.583 | 33.803 | 1.00 | 46.33 | E | C |
| ATOM | 5923 | CG | GLU | E | 202 | −21.875 | 17.009 | 32.608 | 1.00 | 53.67 | E | C |
| ATOM | 5924 | CD | GLU | E | 202 | −21.865 | 15.983 | 31.474 | 1.00 | 58.19 | E | C |
| ATOM | 5925 | OE1 | GLU | E | 202 | −20.766 | 15.479 | 31.128 | 1.00 | 60.08 | E | O |
| ATOM | 5926 | OE2 | GLU | E | 202 | −22.957 | 15.686 | 30.930 | 1.00 | 59.68 | E | O |
| ATOM | 5927 | C | GLU | E | 202 | −19.583 | 17.492 | 35.625 | 1.00 | 39.76 | E | C |
| ATOM | 5928 | O | GLU | E | 202 | −18.667 | 18.273 | 35.376 | 1.00 | 39.82 | E | O |
| ATOM | 5929 | N | ASN | E | 203 | −19.464 | 16.503 | 36.501 | 1.00 | 38.43 | E | N |
| ATOM | 5930 | CA | ASN | E | 203 | −18.216 | 16.293 | 37.222 | 1.00 | 38.57 | E | C |
| ATOM | 5931 | CB | ASN | E | 203 | −18.442 | 15.355 | 38.411 | 1.00 | 39.01 | E | C |
| ATOM | 5932 | CG | ASN | E | 203 | −19.405 | 15.933 | 39.440 | 1.00 | 40.29 | E | C |
| ATOM | 5933 | OD1 | ASN | E | 203 | −19.799 | 15.249 | 40.388 | 1.00 | 40.13 | E | O |
| ATOM | 5934 | ND2 | ASN | E | 203 | −19.789 | 17.196 | 39.257 | 1.00 | 40.78 | E | N |
| ATOM | 5935 | C | ASN | E | 203 | −17.163 | 15.708 | 36.288 | 1.00 | 37.24 | E | C |
| ATOM | 5936 | O | ASN | E | 203 | −17.484 | 14.923 | 35.401 | 1.00 | 38.09 | E | O |
| ATOM | 5937 | N | LEU | E | 204 | −15.907 | 16.095 | 36.489 | 1.00 | 36.45 | E | N |
| ATOM | 5938 | CA | LEU | E | 204 | −14.815 | 15.614 | 35.652 | 1.00 | 36.75 | E | C |
| ATOM | 5939 | CB | LEU | E | 204 | −14.043 | 16.793 | 35.058 | 1.00 | 37.41 | E | C |
| ATOM | 5940 | CG | LEU | E | 204 | −14.832 | 17.773 | 34.189 | 1.00 | 37.73 | E | C |
| ATOM | 5941 | CD1 | LEU | E | 204 | −13.941 | 18.952 | 33.834 | 1.00 | 37.16 | E | C |
| ATOM | 5942 | CD2 | LEU | E | 204 | −15.328 | 17.073 | 32.937 | 1.00 | 36.35 | E | C |
| ATOM | 5943 | C | LEU | E | 204 | −13.849 | 14.719 | 36.412 | 1.00 | 36.59 | E | C |
| ATOM | 5944 | O | LEU | E | 204 | −12.888 | 14.207 | 35.842 | 1.00 | 37.92 | E | O |
| ATOM | 5945 | N | GLY | E | 205 | −14.098 | 14.549 | 37.703 | 1.00 | 36.20 | E | N |
| ATOM | 5946 | CA | GLY | E | 205 | −13.253 | 13.703 | 38.522 | 1.00 | 36.18 | E | C |
| ATOM | 5947 | C | GLY | E | 205 | −11.748 | 13.774 | 38.321 | 1.00 | 36.55 | E | C |
| ATOM | 5948 | O | GLY | E | 205 | −11.068 | 12.751 | 38.446 | 1.00 | 37.37 | E | O |
| ATOM | 5949 | N | TYR | E | 206 | −11.208 | 14.949 | 38.009 | 1.00 | 36.91 | E | N |
| ATOM | 5950 | CA | TYR | E | 206 | −9.759 | 15.070 | 37.841 | 1.00 | 37.07 | E | C |
| ATOM | 5951 | CB | TYR | E | 206 | −9.387 | 16.403 | 37.194 | 1.00 | 38.84 | E | C |
| ATOM | 5952 | CG | TYR | E | 206 | −9.800 | 16.543 | 35.749 | 1.00 | 41.81 | E | C |
| ATOM | 5953 | CD1 | TYR | E | 206 | −9.782 | 15.448 | 34.883 | 1.00 | 43.07 | E | C |
| ATOM | 5954 | CE1 | TYR | E | 206 | −10.152 | 15.582 | 33.547 | 1.00 | 43.48 | E | C |
| ATOM | 5955 | CD2 | TYR | E | 206 | −10.199 | 17.779 | 35.241 | 1.00 | 41.75 | E | C |
| ATOM | 5956 | CE2 | TYR | E | 206 | −10.571 | 17.927 | 33.910 | 1.00 | 43.04 | E | C |
| ATOM | 5957 | CZ | TYR | E | 206 | −10.546 | 16.826 | 33.067 | 1.00 | 44.23 | E | C |
| ATOM | 5958 | OH | TYR | E | 206 | −10.924 | 16.971 | 31.749 | 1.00 | 44.96 | E | O |
| ATOM | 5959 | C | TYR | E | 206 | −9.120 | 15.012 | 39.224 | 1.00 | 36.95 | E | C |
| ATOM | 5960 | O | TYR | E | 206 | −9.813 | 15.105 | 40.239 | 1.00 | 37.17 | E | O |
| ATOM | 5961 | N | HIS | E | 207 | −7.803 | 14.863 | 39.270 | 1.00 | 36.75 | E | N |
| ATOM | 5962 | CA | HIS | E | 207 | −7.113 | 14.815 | 40.549 | 1.00 | 37.33 | E | C |
| ATOM | 5963 | CB | HIS | E | 207 | −6.105 | 13.664 | 40.576 | 1.00 | 38.71 | E | C |
| ATOM | 5964 | CG | HIS | E | 207 | −5.532 | 13.403 | 41.934 | 1.00 | 42.76 | E | C |
| ATOM | 5965 | CD2 | HIS | E | 207 | −6.115 | 12.973 | 43.081 | 1.00 | 44.19 | E | C |
| ATOM | 5966 | ND1 | HIS | E | 207 | −4.204 | 13.620 | 42.237 | 1.00 | 44.94 | E | N |
| ATOM | 5967 | CE1 | HIS | E | 207 | −3.993 | 13.336 | 43.512 | 1.00 | 45.59 | E | C |
| ATOM | 5968 | NE2 | HIS | E | 207 | −5.136 | 12.942 | 44.046 | 1.00 | 45.70 | E | N |
| ATOM | 5969 | C | HIS | E | 207 | −6.399 | 16.138 | 40.812 | 1.00 | 37.58 | E | C |
| ATOM | 5970 | O | HIS | E | 207 | −5.541 | 16.556 | 40.033 | 1.00 | 38.53 | E | O |
| ATOM | 5971 | N | LEU | E | 208 | −6.761 | 16.796 | 41.910 | 1.00 | 35.67 | E | N |
| ATOM | 5972 | CA | LEU | E | 208 | −6.160 | 18.071 | 42.274 | 1.00 | 33.28 | E | C |
| ATOM | 5973 | CB | LEU | E | 208 | −7.219 | 18.993 | 42.877 | 1.00 | 31.42 | E | C |
| ATOM | 5974 | CG | LEU | E | 208 | −8.384 | 19.298 | 41.934 | 1.00 | 30.07 | E | C |
| ATOM | 5975 | CD1 | LEU | E | 208 | −9.496 | 19.991 | 42.688 | 1.00 | 29.12 | E | C |
| ATOM | 5976 | CD2 | LEU | E | 208 | −7.895 | 20.160 | 40.777 | 1.00 | 31.95 | E | C |
| ATOM | 5977 | C | LEU | E | 208 | −5.021 | 17.862 | 43.260 | 1.00 | 34.04 | E | C |
| ATOM | 5978 | O | LEU | E | 208 | −5.135 | 17.084 | 44.203 | 1.00 | 34.85 | E | O |
| ATOM | 5979 | N | LYS | E | 209 | −3.918 | 18.562 | 43.038 | 1.00 | 35.10 | E | N |
| ATOM | 5980 | CA | LYS | E | 209 | −2.759 | 18.437 | 43.906 | 1.00 | 35.83 | E | C |
| ATOM | 5981 | CB | LYS | E | 209 | −1.843 | 17.327 | 43.390 | 1.00 | 37.30 | E | C |
| ATOM | 5982 | CG | LYS | E | 209 | −1.040 | 16.627 | 44.471 | 1.00 | 38.95 | E | C |
| ATOM | 5983 | CD | LYS | E | 209 | 0.191 | 15.950 | 43.891 | 1.00 | 40.79 | E | C |
| ATOM | 5984 | CE | LYS | E | 209 | 1.172 | 15.564 | 44.996 | 1.00 | 43.58 | E | C |
| ATOM | 5985 | NZ | LYS | E | 209 | 2.259 | 14.667 | 44.508 | 1.00 | 44.03 | E | N |
| ATOM | 5986 | C | LYS | E | 209 | −1.983 | 19.747 | 43.983 | 1.00 | 35.54 | E | C |
| ATOM | 5987 | O | LYS | E | 209 | −1.771 | 20.419 | 42.973 | 1.00 | 34.81 | E | O |
| ATOM | 5988 | N | MET | E | 210 | −1.563 | 20.102 | 45.192 | 1.00 | 34.66 | E | N |
| ATOM | 5989 | CA | MET | E | 210 | −0.806 | 21.321 | 45.416 | 1.00 | 33.72 | E | C |
| ATOM | 5990 | CB | MET | E | 210 | −0.834 | 21.682 | 46.907 | 1.00 | 33.86 | E | C |
| ATOM | 5991 | CG | MET | E | 210 | −0.479 | 23.134 | 47.215 | 1.00 | 35.25 | E | C |
| ATOM | 5992 | SD | MET | E | 210 | −1.884 | 24.283 | 47.141 | 1.00 | 36.61 | E | S |
| ATOM | 5993 | CE | MET | E | 210 | −3.250 | 23.150 | 47.070 | 1.00 | 33.18 | E | C |
| ATOM | 5994 | C | MET | E | 210 | 0.630 | 21.093 | 44.962 | 1.00 | 33.46 | E | C |
| ATOM | 5995 | O | MET | E | 210 | 1.206 | 20.038 | 45.223 | 1.00 | 34.28 | E | O |
| ATOM | 5996 | N | LYS | E | 211 | 1.205 | 22.073 | 44.275 | 1.00 | 33.21 | E | N |
| ATOM | 5997 | CA | LYS | E | 211 | 2.583 | 21.956 | 43.815 | 1.00 | 33.16 | E | C |
| ATOM | 5998 | CB | LYS | E | 211 | 2.627 | 21.510 | 42.358 | 1.00 | 34.76 | E | C |
| ATOM | 5999 | CG | LYS | E | 211 | 3.952 | 20.888 | 41.970 | 1.00 | 35.15 | E | C |
| ATOM | 6000 | CD | LYS | E | 211 | 4.477 | 21.498 | 40.687 | 1.00 | 39.43 | E | C |
| ATOM | 6001 | CE | LYS | E | 211 | 4.705 | 20.431 | 39.633 | 1.00 | 39.69 | E | C |
| ATOM | 6002 | NZ | LYS | E | 211 | 5.901 | 19.614 | 39.970 | 1.00 | 42.85 | E | N |
| ATOM | 6003 | C | LYS | E | 211 | 3.333 | 23.269 | 43.970 | 1.00 | 33.30 | E | C |
| ATOM | 6004 | O | LYS | E | 211 | 3.112 | 24.219 | 43.217 | 1.00 | 34.15 | E | O |
| ATOM | 6005 | N | ASP | E | 212 | 4.221 | 23.310 | 44.958 | 1.00 | 32.73 | E | N |
| ATOM | 6006 | CA | ASP | E | 212 | 5.010 | 24.499 | 45.244 | 1.00 | 32.43 | E | C |
| ATOM | 6007 | CB | ASP | E | 212 | 6.041 | 24.733 | 44.137 | 1.00 | 34.22 | E | C |
| ATOM | 6008 | CG | ASP | E | 212 | 7.163 | 23.706 | 44.158 | 1.00 | 37.27 | E | C |
| ATOM | 6009 | OD1 | ASP | E | 212 | 7.556 | 23.255 | 45.258 | 1.00 | 38.11 | E | O |
| ATOM | 6010 | OD2 | ASP | E | 212 | 7.654 | 23.347 | 43.068 | 1.00 | 40.29 | E | O |
| ATOM | 6011 | C | ASP | E | 212 | 4.131 | 25.738 | 45.412 | 1.00 | 30.59 | E | C |
| ATOM | 6012 | O | ASP | E | 212 | 4.489 | 26.830 | 44.977 | 1.00 | 30.41 | E | O |
| ATOM | 6013 | N | GLY | E | 213 | 2.976 | 25.558 | 46.043 | 1.00 | 29.78 | E | N |
| ATOM | 6014 | CA | GLY | E | 213 | 2.083 | 26.677 | 46.281 | 1.00 | 28.12 | E | C |
| ATOM | 6015 | C | GLY | E | 213 | 0.973 | 26.876 | 45.269 | 1.00 | 28.12 | E | C |
| ATOM | 6016 | O | GLY | E | 213 | 0.144 | 27.772 | 45.434 | 1.00 | 28.23 | E | O |
| ATOM | 6017 | N | VAL | E | 214 | 0.937 | 26.052 | 44.227 | 1.00 | 27.70 | E | N |
| ATOM | 6018 | CA | VAL | E | 214 | −0.101 | 26.197 | 43.211 | 1.00 | 27.19 | E | C |
| ATOM | 6019 | CB | VAL | E | 214 | 0.505 | 26.629 | 41.847 | 1.00 | 27.92 | E | C |
| ATOM | 6020 | CG1 | VAL | E | 214 | −0.607 | 26.929 | 40.844 | 1.00 | 26.64 | E | C |
| ATOM | 6021 | CG2 | VAL | E | 214 | 1.384 | 27.857 | 42.036 | 1.00 | 26.82 | E | C |
| ATOM | 6022 | C | VAL | E | 214 | −0.881 | 24.912 | 43.010 | 1.00 | 26.37 | E | C |
| ATOM | 6023 | O | VAL | E | 214 | −0.307 | 23.827 | 42.993 | 1.00 | 28.68 | E | O |
| ATOM | 6024 | N | VAL | E | 215 | −2.195 | 25.035 | 42.867 | 1.00 | 26.02 | E | N |
| ATOM | 6025 | CA | VAL | E | 215 | −3.035 | 23.867 | 42.646 | 1.00 | 26.15 | E | C |
| ATOM | 6026 | CB | VAL | E | 215 | −4.542 | 24.191 | 42.832 | 1.00 | 25.99 | E | C |
| ATOM | 6027 | CG1 | VAL | E | 215 | −5.384 | 22.933 | 42.590 | 1.00 | 22.29 | E | C |
| ATOM | 6028 | CG2 | VAL | E | 215 | −4.792 | 24.745 | 44.235 | 1.00 | 23.78 | E | C |
| ATOM | 6029 | C | VAL | E | 215 | −2.817 | 23.396 | 41.212 | 1.00 | 28.77 | E | C |
| ATOM | 6030 | O | VAL | E | 215 | −3.038 | 24.152 | 40.262 | 1.00 | 28.51 | E | O |
| ATOM | 6031 | N | TYR | E | 216 | −2.369 | 22.155 | 41.061 | 1.00 | 30.02 | E | N |
| ATOM | 6032 | CA | TYR | E | 216 | −2.136 | 21.581 | 39.740 | 1.00 | 31.22 | E | C |
| ATOM | 6033 | CB | TYR | E | 216 | −0.765 | 20.918 | 39.682 | 1.00 | 30.99 | E | C |
| ATOM | 6034 | CG | TYR | E | 216 | 0.321 | 21.862 | 39.251 | 1.00 | 31.97 | E | C |
| ATOM | 6035 | CD1 | TYR | E | 216 | 1.085 | 21.608 | 38.113 | 1.00 | 31.11 | E | C |
| ATOM | 6036 | CE1 | TYR | E | 216 | 2.086 | 22.485 | 37.712 | 1.00 | 32.85 | E | C |
| ATOM | 6037 | CD2 | TYR | E | 216 | 0.584 | 23.020 | 39.978 | 1.00 | 33.39 | E | C |
| ATOM | 6038 | CE2 | TYR | E | 216 | 1.584 | 23.905 | 39.586 | 1.00 | 33.66 | E | C |
| ATOM | 6039 | CZ | TYR | E | 216 | 2.330 | 23.630 | 38.453 | 1.00 | 33.35 | E | C |
| ATOM | 6040 | OH | TYR | E | 216 | 3.327 | 24.500 | 38.074 | 1.00 | 36.44 | E | O |
| ATOM | 6041 | C | TYR | E | 216 | −3.207 | 20.552 | 39.438 | 1.00 | 32.45 | E | C |
| ATOM | 6042 | O | TYR | E | 216 | −3.600 | 19.778 | 40.311 | 1.00 | 31.97 | E | O |
| ATOM | 6043 | N | ILE | E | 217 | −3.688 | 20.549 | 38.202 | 1.00 | 34.49 | E | N |
| ATOM | 6044 | CA | ILE | E | 217 | −4.725 | 19.600 | 37.811 | 1.00 | 37.57 | E | C |
| ATOM | 6045 | CB | ILE | E | 217 | −5.813 | 20.268 | 36.948 | 1.00 | 36.47 | E | C |
| ATOM | 6046 | CG2 | ILE | E | 217 | −6.867 | 19.242 | 36.567 | 1.00 | 35.59 | E | C |
| ATOM | 6047 | CG1 | ILE | E | 217 | −6.447 | 21.434 | 37.713 | 1.00 | 36.29 | E | C |
| ATOM | 6048 | CD1 | ILE | E | 217 | −6.207 | 22.789 | 37.068 | 1.00 | 36.52 | E | C |
| ATOM | 6049 | C | ILE | E | 217 | −4.124 | 18.446 | 37.024 | 1.00 | 38.89 | E | C |
| ATOM | 6050 | O | ILE | E | 217 | −3.423 | 18.654 | 36.031 | 1.00 | 38.98 | E | O |
| ATOM | 6051 | N | TYR | E | 218 | −4.391 | 17.230 | 37.487 | 1.00 | 40.17 | E | N |
| ATOM | 6052 | CA | TYR | E | 218 | −3.890 | 16.035 | 36.830 | 1.00 | 41.90 | E | C |
| ATOM | 6053 | CB | TYR | E | 218 | −3.091 | 15.179 | 37.810 | 1.00 | 38.57 | E | C |
| ATOM | 6054 | CG | TYR | E | 218 | −1.847 | 15.879 | 38.276 | 1.00 | 37.25 | E | C |
| ATOM | 6055 | CD1 | TYR | E | 218 | −0.637 | 15.701 | 37.612 | 1.00 | 37.10 | E | C |
| ATOM | 6056 | CE1 | TYR | E | 218 | 0.504 | 16.402 | 37.993 | 1.00 | 36.61 | E | C |
| ATOM | 6057 | CD2 | TYR | E | 218 | −1.887 | 16.775 | 39.343 | 1.00 | 37.25 | E | C |
| ATOM | 6058 | CE2 | TYR | E | 218 | −0.756 | 17.481 | 39.733 | 1.00 | 37.37 | E | C |
| ATOM | 6059 | CZ | TYR | E | 218 | 0.437 | 17.291 | 39.051 | 1.00 | 37.65 | E | C |
| ATOM | 6060 | OH | TYR | E | 218 | 1.560 | 17.998 | 39.419 | 1.00 | 39.83 | E | O |
| ATOM | 6061 | C | TYR | E | 218 | −5.090 | 15.278 | 36.317 | 1.00 | 45.46 | E | C |
| ATOM | 6062 | O | TYR | E | 218 | −6.074 | 15.077 | 37.037 | 1.00 | 45.58 | E | O |
| ATOM | 6063 | N | ALA | E | 219 | −5.014 | 14.884 | 35.052 | 1.00 | 49.85 | E | N |
| ATOM | 6064 | CA | ALA | E | 219 | −6.095 | 14.156 | 34.418 | 1.00 | 53.89 | E | C |
| ATOM | 6065 | CB | ALA | E | 219 | −5.653 | 13.640 | 33.053 | 1.00 | 54.99 | E | C |
| ATOM | 6066 | C | ALA | E | 219 | −6.500 | 13.000 | 35.307 | 1.00 | 57.12 | E | C |
| ATOM | 6067 | O | ALA | E | 219 | −5.645 | 12.340 | 35.896 | 1.00 | 56.83 | E | O |
| ATOM | 6068 | N | ASN | E | 220 | −7.810 | 12.792 | 35.403 | 1.00 | 60.36 | E | N |
| ATOM | 6069 | CA | ASN | E | 220 | −8.424 | 11.724 | 36.188 | 1.00 | 63.59 | E | C |
| ATOM | 6070 | CB | ASN | E | 220 | −9.672 | 11.225 | 35.446 | 1.00 | 65.26 | E | C |
| ATOM | 6071 | CG | ASN | E | 220 | −9.915 | 11.980 | 34.136 | 1.00 | 66.08 | E | C |
| ATOM | 6072 | OD1 | ASN | E | 220 | −10.953 | 12.621 | 33.956 | 1.00 | 66.66 | E | O |
| ATOM | 6073 | ND2 | ASN | E | 220 | −8.952 | 11.906 | 33.221 | 1.00 | 66.75 | E | N |
| ATOM | 6074 | C | ASN | E | 220 | −7.450 | 10.567 | 36.432 | 1.00 | 65.38 | E | C |
| ATOM | 6075 | O | ASN | E | 220 | −7.640 | 9.451 | 35.939 | 1.00 | 66.02 | E | O |
| ATOM | 6076 | N | GLU | E | 221 | −6.414 | 10.843 | 37.214 | 1.00 | 65.35 | E | N |
| ATOM | 6077 | CA | GLU | E | 221 | −5.396 | 9.851 | 37.497 | 1.00 | 65.75 | E | C |
| ATOM | 6078 | CB | GLU | E | 221 | −4.443 | 9.724 | 36.309 | 1.00 | 67.25 | E | C |
| ATOM | 6079 | CG | GLU | E | 221 | −4.590 | 8.454 | 35.506 | 1.00 | 70.93 | E | C |
| ATOM | 6080 | CD | GLU | E | 221 | −3.711 | 8.455 | 34.265 | 1.00 | 73.98 | E | C |
| ATOM | 6081 | OE1 | GLU | E | 221 | −2.486 | 8.670 | 34.404 | 1.00 | 75.28 | E | O |
| ATOM | 6082 | OE2 | GLU | E | 221 | −4.244 | 8.242 | 33.152 | 1.00 | 75.32 | E | O |
| ATOM | 6083 | C | GLU | E | 221 | −4.593 | 10.266 | 38.706 | 1.00 | 64.83 | E | C |
| ATOM | 6084 | O | GLU | E | 221 | −3.880 | 11.271 | 38.669 | 1.00 | 63.95 | E | O |
| ATOM | 6085 | N | ALA | E | 222 | −4.707 | 9.493 | 39.780 | 1.00 | 64.51 | E | N |
| ATOM | 6086 | CA | ALA | E | 222 | −3.936 | 9.772 | 40.977 | 1.00 | 64.47 | E | C |
| ATOM | 6087 | CB | ALA | E | 222 | −4.299 | 8.786 | 42.088 | 1.00 | 63.64 | E | C |
| ATOM | 6088 | C | ALA | E | 222 | −2.486 | 9.582 | 40.522 | 1.00 | 64.24 | E | C |
| ATOM | 6089 | O | ALA | E | 222 | −1.545 | 9.690 | 41.310 | 1.00 | 63.91 | E | O |
| ATOM | 6090 | N | ALA | E | 223 | −2.336 | 9.295 | 39.228 | 1.00 | 64.41 | E | N |
| ATOM | 6091 | CA | ALA | E | 223 | −1.042 | 9.103 | 38.587 | 1.00 | 65.18 | E | C |
| ATOM | 6092 | CB | ALA | E | 223 | −1.236 | 8.533 | 37.193 | 1.00 | 64.36 | E | C |
| ATOM | 6093 | C | ALA | E | 223 | −0.325 | 10.451 | 38.510 | 1.00 | 66.53 | E | C |
| ATOM | 6094 | O | ALA | E | 223 | 0.386 | 10.747 | 37.546 | 1.00 | 66.35 | E | O |
| ATOM | 6095 | N | ALA | E | 224 | −0.548 | 11.273 | 39.529 | 1.00 | 67.47 | E | N |
| ATOM | 6096 | CA | ALA | E | 224 | 0.082 | 12.575 | 39.627 | 1.00 | 66.62 | E | C |
| ATOM | 6097 | CB | ALA | E | 224 | −0.661 | 13.439 | 40.628 | 1.00 | 66.55 | E | C |
| ATOM | 6098 | C | ALA | E | 224 | 1.497 | 12.301 | 40.113 | 1.00 | 67.66 | E | C |
| ATOM | 6099 | O | ALA | E | 224 | 2.317 | 13.217 | 40.220 | 1.00 | 67.77 | E | O |
| ATOM | 6100 | N | GLY | E | 225 | 1.760 | 11.026 | 40.416 | 1.00 | 68.65 | E | N |
| ATOM | 6101 | CA | GLY | E | 225 | 3.073 | 10.601 | 40.879 | 1.00 | 68.33 | E | C |
| ATOM | 6102 | C | GLY | E | 225 | 4.091 | 11.043 | 39.851 | 1.00 | 68.53 | E | C |
| ATOM | 6103 | O | GLY | E | 225 | 5.193 | 11.492 | 40.181 | 1.00 | 68.63 | E | O |
| ATOM | 6104 | N | LYS | E | 226 | 3.714 | 10.894 | 38.587 | 1.00 | 67.94 | E | N |
| ATOM | 6105 | CA | LYS | E | 226 | 4.558 | 11.333 | 37.492 | 1.00 | 67.08 | E | C |
| ATOM | 6106 | CB | LYS | E | 226 | 4.407 | 10.410 | 36.285 | 1.00 | 67.93 | E | C |
| ATOM | 6107 | CG | LYS | E | 226 | 5.678 | 10.277 | 35.462 | 1.00 | 69.37 | E | C |
| ATOM | 6108 | CD | LYS | E | 226 | 6.675 | 9.338 | 36.131 | 1.00 | 70.00 | E | C |
| ATOM | 6109 | CE | LYS | E | 226 | 7.538 | 8.620 | 35.103 | 1.00 | 70.88 | E | C |
| ATOM | 6110 | NZ | LYS | E | 226 | 6.975 | 7.291 | 34.724 | 1.00 | 71.97 | E | N |
| ATOM | 6111 | C | LYS | E | 226 | 4.003 | 12.717 | 37.172 | 1.00 | 66.09 | E | C |
| ATOM | 6112 | O | LYS | E | 226 | 2.892 | 12.842 | 36.653 | 1.00 | 65.87 | E | O |
| ATOM | 6113 | N | ASP | E | 227 | 4.759 | 13.750 | 37.525 | 1.00 | 64.13 | E | N |
| ATOM | 6114 | CA | ASP | E | 227 | 4.331 | 15.119 | 37.284 | 1.00 | 61.83 | E | C |
| ATOM | 6115 | CB | ASP | E | 227 | 5.467 | 16.088 | 37.603 | 1.00 | 63.09 | E | C |
| ATOM | 6116 | CG | ASP | E | 227 | 5.232 | 16.849 | 38.890 | 1.00 | 65.24 | E | C |
| ATOM | 6117 | OD1 | ASP | E | 227 | 5.989 | 16.621 | 39.862 | 1.00 | 65.39 | E | O |
| ATOM | 6118 | OD2 | ASP | E | 227 | 4.286 | 17.671 | 38.926 | 1.00 | 65.88 | E | O |
| ATOM | 6119 | C | ASP | E | 227 | 3.890 | 15.296 | 35.839 | 1.00 | 59.24 | E | C |
| ATOM | 6120 | O | ASP | E | 227 | 4.669 | 15.720 | 34.987 | 1.00 | 58.43 | E | O |
| ATOM | 6121 | N | GLU | E | 228 | 2.633 | 14.962 | 35.573 | 1.00 | 56.36 | E | N |
| ATOM | 6122 | CA | GLU | E | 228 | 2.075 | 15.075 | 34.236 | 1.00 | 53.71 | E | C |
| ATOM | 6123 | CB | GLU | E | 228 | 2.003 | 13.695 | 33.582 | 1.00 | 55.13 | E | C |
| ATOM | 6124 | CG | GLU | E | 228 | 3.328 | 13.236 | 32.987 | 1.00 | 57.34 | E | C |
| ATOM | 6125 | CD | GLU | E | 228 | 3.456 | 11.722 | 32.905 | 1.00 | 59.33 | E | C |
| ATOM | 6126 | OE1 | GLU | E | 228 | 2.415 | 11.031 | 32.824 | 1.00 | 60.00 | E | O |
| ATOM | 6127 | OE2 | GLU | E | 228 | 4.605 | 11.225 | 32.920 | 1.00 | 60.72 | E | O |
| ATOM | 6128 | C | GLU | E | 228 | 0.685 | 15.686 | 34.332 | 1.00 | 51.74 | E | C |
| ATOM | 6129 | O | GLU | E | 228 | −0.318 | 15.028 | 34.052 | 1.00 | 51.51 | E | O |
| ATOM | 6130 | N | PRO | E | 229 | 0.611 | 16.967 | 34.730 | 1.00 | 49.11 | E | N |
| ATOM | 6131 | CD | PRO | E | 229 | 1.755 | 17.836 | 35.057 | 1.00 | 48.20 | E | C |
| ATOM | 6132 | CA | PRO | E | 229 | −0.664 | 17.674 | 34.870 | 1.00 | 47.34 | E | C |
| ATOM | 6133 | CB | PRO | E | 229 | −0.258 | 19.045 | 35.409 | 1.00 | 47.70 | E | C |
| ATOM | 6134 | CG | PRO | E | 229 | 1.165 | 19.211 | 34.978 | 1.00 | 46.26 | E | C |
| ATOM | 6135 | C | PRO | E | 229 | −1.402 | 17.788 | 33.551 | 1.00 | 46.29 | E | C |
| ATOM | 6136 | O | PRO | E | 229 | −0.817 | 17.607 | 32.488 | 1.00 | 45.47 | E | O |
| ATOM | 6137 | N | LYS | E | 230 | −2.695 | 18.079 | 33.627 | 1.00 | 46.50 | E | N |
| ATOM | 6138 | CA | LYS | E | 230 | −3.501 | 18.240 | 32.429 | 1.00 | 46.52 | E | C |
| ATOM | 6139 | CB | LYS | E | 230 | −4.944 | 18.596 | 32.796 | 1.00 | 47.37 | E | C |
| ATOM | 6140 | CG | LYS | E | 230 | −5.910 | 17.421 | 32.782 | 1.00 | 50.37 | E | C |
| ATOM | 6141 | CD | LYS | E | 230 | −6.191 | 16.956 | 31.361 | 1.00 | 52.18 | E | C |
| ATOM | 6142 | CE | LYS | E | 230 | −7.651 | 16.568 | 31.186 | 1.00 | 52.81 | E | C |
| ATOM | 6143 | NZ | LYS | E | 230 | −7.863 | 15.115 | 31.442 | 1.00 | 53.37 | E | N |
| ATOM | 6144 | C | LYS | E | 230 | −2.877 | 19.395 | 31.667 | 1.00 | 47.41 | E | C |
| ATOM | 6145 | O | LYS | E | 230 | −2.528 | 20.416 | 32.264 | 1.00 | 46.87 | E | O |
| ATOM | 6146 | N | PRO | E | 231 | −2.709 | 19.246 | 30.341 | 1.00 | 48.45 | E | N |
| ATOM | 6147 | CD | PRO | E | 231 | −3.049 | 18.076 | 29.507 | 1.00 | 48.83 | E | C |
| ATOM | 6148 | CA | PRO | E | 231 | −2.113 | 20.325 | 29.548 | 1.00 | 48.01 | E | C |
| ATOM | 6149 | CB | PRO | E | 231 | −2.408 | 19.914 | 28.111 | 1.00 | 47.49 | E | C |
| ATOM | 6150 | CG | PRO | E | 231 | −2.438 | 18.416 | 28.168 | 1.00 | 48.80 | E | C |
| ATOM | 6151 | C | PRO | E | 231 | −2.725 | 21.672 | 29.905 | 1.00 | 47.90 | E | C |
| ATOM | 6152 | O | PRO | E | 231 | −3.940 | 21.858 | 29.826 | 1.00 | 47.52 | E | O |
| ATOM | 6153 | N | LEU | E | 232 | −1.867 | 22.602 | 30.312 | 1.00 | 48.81 | E | N |
| ATOM | 6154 | CA | LEU | E | 232 | −2.296 | 23.943 | 30.700 | 1.00 | 48.13 | E | C |
| ATOM | 6155 | CB | LEU | E | 232 | −3.103 | 23.883 | 31.998 | 1.00 | 47.27 | E | C |
| ATOM | 6156 | CG | LEU | E | 232 | −4.069 | 25.032 | 32.282 | 1.00 | 46.76 | E | C |
| ATOM | 6157 | CD1 | LEU | E | 232 | −5.313 | 24.489 | 32.991 | 1.00 | 45.48 | E | C |
| ATOM | 6158 | CD2 | LEU | E | 232 | −3.368 | 26.082 | 33.134 | 1.00 | 47.27 | E | C |
| ATOM | 6159 | C | LEU | E | 232 | −1.073 | 24.830 | 30.904 | 1.00 | 48.16 | E | C |
| ATOM | 6160 | O | LEU | E | 232 | 0.043 | 24.332 | 31.109 | 1.00 | 48.86 | E | O |
| ATOM | 6161 | N | LEU | E | 233 | −1.280 | 26.141 | 30.834 | 1.00 | 46.41 | E | N |
| ATOM | 6162 | CA | LEU | E | 233 | −0.188 | 27.085 | 31.031 | 1.00 | 45.49 | E | C |
| ATOM | 6163 | CB | LEU | E | 233 | −0.367 | 28.311 | 30.123 | 1.00 | 48.13 | E | C |
| ATOM | 6164 | CG | LEU | E | 233 | −1.610 | 29.180 | 30.363 | 1.00 | 49.17 | E | C |
| ATOM | 6165 | CD1 | LEU | E | 233 | −1.429 | 30.538 | 29.693 | 1.00 | 49.58 | E | C |
| ATOM | 6166 | CD2 | LEU | E | 233 | −2.845 | 28.468 | 29.830 | 1.00 | 49.92 | E | C |
| ATOM | 6167 | C | LEU | E | 233 | −0.190 | 27.499 | 32.505 | 1.00 | 42.71 | E | C |
| ATOM | 6168 | O | LEU | E | 233 | −1.071 | 28.238 | 32.962 | 1.00 | 40.55 | E | O |
| ATOM | 6169 | N | TYR | E | 234 | 0.790 | 26.989 | 33.246 | 1.00 | 40.17 | E | N |
| ATOM | 6170 | CA | TYR | E | 234 | 0.918 | 27.283 | 34.669 | 1.00 | 36.43 | E | C |
| ATOM | 6171 | CB | TYR | E | 234 | 1.396 | 26.031 | 35.424 | 1.00 | 34.93 | E | C |
| ATOM | 6172 | CG | TYR | E | 234 | 0.388 | 24.895 | 35.430 | 1.00 | 33.61 | E | C |
| ATOM | 6173 | CD1 | TYR | E | 234 | 0.356 | 23.963 | 34.394 | 1.00 | 33.12 | E | C |
| ATOM | 6174 | CE1 | TYR | E | 234 | −0.583 | 22.932 | 34.379 | 1.00 | 33.29 | E | C |
| ATOM | 6175 | CD2 | TYR | E | 234 | −0.548 | 24.765 | 36.460 | 1.00 | 31.47 | E | C |
| ATOM | 6176 | CE2 | TYR | E | 234 | −1.491 | 23.739 | 36.455 | 1.00 | 31.52 | E | C |
| ATOM | 6177 | CZ | TYR | E | 234 | −1.503 | 22.825 | 35.409 | 1.00 | 33.40 | E | C |
| ATOM | 6178 | OH | TYR | E | 234 | −2.431 | 21.803 | 35.377 | 1.00 | 33.29 | E | O |
| ATOM | 6179 | C | TYR | E | 234 | 1.910 | 28.428 | 34.855 | 1.00 | 34.85 | E | C |
| ATOM | 6180 | O | TYR | E | 234 | 2.691 | 28.740 | 33.951 | 1.00 | 34.19 | E | O |
| ATOM | 6181 | N | PRO | E | 235 | 1.893 | 29.072 | 36.033 | 1.00 | 32.90 | E | N |
| ATOM | 6182 | CD | PRO | E | 235 | 1.023 | 28.783 | 37.183 | 1.00 | 31.51 | E | C |
| ATOM | 6183 | CA | PRO | E | 235 | 2.806 | 30.189 | 36.304 | 1.00 | 31.30 | E | C |
| ATOM | 6184 | CB | PRO | E | 235 | 2.424 | 30.642 | 37.715 | 1.00 | 31.43 | E | C |
| ATOM | 6185 | CG | PRO | E | 235 | 1.074 | 30.054 | 37.962 | 1.00 | 32.26 | E | C |
| ATOM | 6186 | C | PRO | E | 235 | 4.269 | 29.780 | 36.224 | 1.00 | 29.94 | E | C |
| ATOM | 6187 | O | PRO | E | 235 | 4.619 | 28.641 | 36.514 | 1.00 | 31.56 | E | O |
| ATOM | 6188 | N | ASN | E | 236 | 5.120 | 30.719 | 35.834 | 1.00 | 29.28 | E | N |
| ATOM | 6189 | CA | ASN | E | 236 | 6.551 | 30.469 | 35.723 | 1.00 | 29.67 | E | C |
| ATOM | 6190 | CB | ASN | E | 236 | 7.006 | 30.694 | 34.283 | 1.00 | 29.78 | E | C |
| ATOM | 6191 | CG | ASN | E | 236 | 8.445 | 30.302 | 34.061 | 1.00 | 32.24 | E | C |
| ATOM | 6192 | OD1 | ASN | E | 236 | 9.315 | 30.591 | 34.882 | 1.00 | 33.06 | E | O |
| ATOM | 6193 | ND2 | ASN | E | 236 | 8.707 | 29.638 | 32.943 | 1.00 | 35.23 | E | N |
| ATOM | 6194 | C | ASN | E | 236 | 7.271 | 31.440 | 36.654 | 1.00 | 29.64 | E | C |
| ATOM | 6195 | O | ASN | E | 236 | 7.530 | 32.589 | 36.283 | 1.00 | 29.18 | E | O |
| ATOM | 6196 | N | MET | E | 237 | 7.605 | 30.972 | 37.854 | 1.00 | 29.10 | E | N |
| ATOM | 6197 | CA | MET | E | 237 | 8.255 | 31.827 | 38.838 | 1.00 | 29.85 | E | C |
| ATOM | 6198 | CB | MET | E | 237 | 8.437 | 31.092 | 40.161 | 1.00 | 32.34 | E | C |
| ATOM | 6199 | CG | MET | E | 237 | 8.757 | 32.049 | 41.298 | 1.00 | 35.35 | E | C |
| ATOM | 6200 | SD | MET | E | 237 | 8.705 | 31.267 | 42.886 | 1.00 | 40.35 | E | S |
| ATOM | 6201 | CE | MET | E | 237 | 10.478 | 31.066 | 43.211 | 1.00 | 40.58 | E | C |
| ATOM | 6202 | C | MET | E | 237 | 9.582 | 32.443 | 38.438 | 1.00 | 29.37 | E | C |
| ATOM | 6203 | O | MET | E | 237 | 9.853 | 33.591 | 38.787 | 1.00 | 29.94 | E | O |
| ATOM | 6204 | N | GLU | E | 238 | 10.419 | 31.696 | 37.729 | 1.00 | 28.84 | E | N |
| ATOM | 6205 | CA | GLU | E | 238 | 11.707 | 32.235 | 37.321 | 1.00 | 28.80 | E | C |
| ATOM | 6206 | CB | GLU | E | 238 | 12.532 | 31.172 | 36.599 | 1.00 | 32.05 | E | C |
| ATOM | 6207 | CG | GLU | E | 238 | 14.026 | 31.418 | 36.687 | 1.00 | 40.47 | E | C |
| ATOM | 6208 | CD | GLU | E | 238 | 14.838 | 30.486 | 35.801 | 1.00 | 45.86 | E | C |
| ATOM | 6209 | OE1 | GLU | E | 238 | 15.796 | 30.965 | 35.149 | 1.00 | 47.80 | E | O |
| ATOM | 6210 | OE2 | GLU | E | 238 | 14.521 | 29.275 | 35.759 | 1.00 | 48.59 | E | O |
| ATOM | 6211 | C | GLU | E | 238 | 11.495 | 33.437 | 36.411 | 1.00 | 28.02 | E | C |
| ATOM | 6212 | O | GLU | E | 238 | 12.198 | 34.444 | 36.505 | 1.00 | 30.35 | E | O |
| ATOM | 6213 | N | GLU | E | 239 | 10.513 | 33.322 | 35.531 | 1.00 | 25.99 | E | N |
| ATOM | 6214 | CA | GLU | E | 239 | 10.185 | 34.390 | 34.608 | 1.00 | 24.28 | E | C |
| ATOM | 6215 | CB | GLU | E | 239 | 9.158 | 33.880 | 33.597 | 1.00 | 26.38 | E | C |
| ATOM | 6216 | CG | GLU | E | 239 | 8.719 | 34.885 | 32.546 | 1.00 | 27.87 | E | C |
| ATOM | 6217 | CD | GLU | E | 239 | 7.654 | 34.314 | 31.629 | 1.00 | 29.74 | E | C |
| ATOM | 6218 | OE1 | GLU | E | 239 | 6.960 | 35.098 | 30.946 | 1.00 | 32.51 | E | O |
| ATOM | 6219 | OE2 | GLU | E | 239 | 7.512 | 33.075 | 31.593 | 1.00 | 31.54 | E | O |
| ATOM | 6220 | C | GLU | E | 239 | 9.619 | 35.571 | 35.392 | 1.00 | 23.94 | E | C |
| ATOM | 6221 | O | GLU | E | 239 | 9.976 | 36.721 | 35.147 | 1.00 | 24.30 | E | O |
| ATOM | 6222 | N | PHE | E | 240 | 8.736 | 35.279 | 36.343 | 1.00 | 22.77 | E | N |
| ATOM | 6223 | CA | PHE | E | 240 | 8.127 | 36.319 | 37.161 | 1.00 | 21.73 | E | C |
| ATOM | 6224 | CB | PHE | E | 240 | 7.161 | 35.710 | 38.179 | 1.00 | 20.60 | E | C |
| ATOM | 6225 | CG | PHE | E | 240 | 6.459 | 36.734 | 39.026 | 1.00 | 22.31 | E | C |
| ATOM | 6226 | CD1 | PHE | E | 240 | 7.117 | 37.350 | 40.083 | 1.00 | 21.00 | E | C |
| ATOM | 6227 | CD2 | PHE | E | 240 | 5.142 | 37.095 | 38.755 | 1.00 | 22.54 | E | C |
| ATOM | 6228 | CE1 | PHE | E | 240 | 6.476 | 38.313 | 40.861 | 1.00 | 21.85 | E | C |
| ATOM | 6229 | CE2 | PHE | E | 240 | 4.492 | 38.057 | 39.525 | 1.00 | 23.98 | E | C |
| ATOM | 6230 | CZ | PHE | E | 240 | 5.165 | 38.668 | 40.583 | 1.00 | 22.31 | E | C |
| ATOM | 6231 | C | PHE | E | 240 | 9.189 | 37.115 | 37.899 | 1.00 | 21.59 | E | C |
| ATOM | 6232 | O | PHE | E | 240 | 9.153 | 38.340 | 37.918 | 1.00 | 20.64 | E | O |
| ATOM | 6233 | N | LEU | E | 241 | 10.132 | 36.406 | 38.508 | 1.00 | 22.64 | E | N |
| ATOM | 6234 | CA | LEU | E | 241 | 11.202 | 37.044 | 39.257 | 1.00 | 23.35 | E | C |
| ATOM | 6235 | CB | LEU | E | 241 | 12.009 | 35.988 | 40.017 | 1.00 | 23.89 | E | C |
| ATOM | 6236 | CG | LEU | E | 241 | 11.249 | 35.312 | 41.170 | 1.00 | 27.03 | E | C |
| ATOM | 6237 | CD1 | LEU | E | 241 | 12.039 | 34.120 | 41.705 | 1.00 | 26.50 | E | C |
| ATOM | 6238 | CD2 | LEU | E | 241 | 10.999 | 36.332 | 42.279 | 1.00 | 27.48 | E | C |
| ATOM | 6239 | C | LEU | E | 241 | 12.120 | 37.864 | 38.355 | 1.00 | 25.04 | E | C |
| ATOM | 6240 | O | LEU | E | 241 | 12.676 | 38.877 | 38.784 | 1.00 | 25.25 | E | O |
| ATOM | 6241 | N | ASP | E | 242 | 12.276 | 37.441 | 37.105 | 1.00 | 25.94 | E | N |
| ATOM | 6242 | CA | ASP | E | 242 | 13.130 | 38.177 | 36.177 | 1.00 | 26.57 | E | C |
| ATOM | 6243 | CB | ASP | E | 242 | 13.362 | 37.369 | 34.893 | 1.00 | 31.82 | E | C |
| ATOM | 6244 | CG | ASP | E | 242 | 14.341 | 36.221 | 35.090 | 1.00 | 36.95 | E | C |
| ATOM | 6245 | OD1 | ASP | E | 242 | 15.089 | 36.230 | 36.097 | 1.00 | 40.63 | E | O |
| ATOM | 6246 | OD2 | ASP | E | 242 | 14.362 | 35.308 | 34.234 | 1.00 | 39.35 | E | O |
| ATOM | 6247 | C | ASP | E | 242 | 12.480 | 39.506 | 35.827 | 1.00 | 24.55 | E | C |
| ATOM | 6248 | O | ASP | E | 242 | 13.135 | 40.544 | 35.809 | 1.00 | 22.94 | E | O |
| ATOM | 6249 | N | ASP | E | 243 | 11.182 | 39.461 | 35.552 | 1.00 | 24.54 | E | N |
| ATOM | 6250 | CA | ASP | E | 243 | 10.427 | 40.654 | 35.188 | 1.00 | 23.47 | E | C |
| ATOM | 6251 | CB | ASP | E | 243 | 9.025 | 40.260 | 34.707 | 1.00 | 23.22 | E | C |
| ATOM | 6252 | CG | ASP | E | 243 | 9.046 | 39.576 | 33.348 | 1.00 | 22.40 | E | C |
| ATOM | 6253 | OD1 | ASP | E | 243 | 10.034 | 39.772 | 32.613 | 1.00 | 20.67 | E | O |
| ATOM | 6254 | OD2 | ASP | E | 243 | 8.087 | 38.846 | 33.018 | 1.00 | 18.12 | E | O |
| ATOM | 6255 | C | ASP | E | 243 | 10.327 | 41.607 | 36.370 | 1.00 | 23.89 | E | C |
| ATOM | 6256 | O | ASP | E | 243 | 10.399 | 42.826 | 36.206 | 1.00 | 24.66 | E | O |
| ATOM | 6257 | N | MET | E | 244 | 10.169 | 41.042 | 37.562 | 1.00 | 22.24 | E | N |
| ATOM | 6258 | CA | MET | E | 244 | 10.065 | 41.827 | 38.786 | 1.00 | 21.56 | E | C |
| ATOM | 6259 | CB | MET | E | 244 | 9.742 | 40.906 | 39.960 | 1.00 | 20.20 | E | C |
| ATOM | 6260 | CG | MET | E | 244 | 9.642 | 41.611 | 41.298 | 1.00 | 21.18 | E | C |
| ATOM | 6261 | SD | MET | E | 244 | 9.711 | 40.451 | 42.696 | 1.00 | 23.66 | E | S |
| ATOM | 6262 | CE | MET | E | 244 | 11.436 | 40.038 | 42.722 | 1.00 | 20.65 | E | C |
| ATOM | 6263 | C | MET | E | 244 | 11.369 | 42.571 | 39.066 | 1.00 | 21.70 | E | C |
| ATOM | 6264 | O | MET | E | 244 | 11.368 | 43.747 | 39.441 | 1.00 | 19.61 | E | O |
| ATOM | 6265 | N | ASN | E | 245 | 12.482 | 41.872 | 38.882 | 1.00 | 22.42 | E | N |
| ATOM | 6266 | CA | ASN | E | 245 | 13.793 | 42.457 | 39.111 | 1.00 | 22.62 | E | C |
| ATOM | 6267 | CB | ASN | E | 245 | 14.866 | 41.376 | 39.008 | 1.00 | 23.99 | E | C |
| ATOM | 6268 | CG | ASN | E | 245 | 14.947 | 40.527 | 40.259 | 1.00 | 26.84 | E | C |
| ATOM | 6269 | OD1 | ASN | E | 245 | 14.921 | 41.046 | 41.373 | 1.00 | 27.02 | E | O |
| ATOM | 6270 | ND2 | ASN | E | 245 | 15.041 | 39.215 | 40.083 | 1.00 | 28.42 | E | N |
| ATOM | 6271 | C | ASN | E | 245 | 14.076 | 43.579 | 38.121 | 1.00 | 22.10 | E | C |
| ATOM | 6272 | O | ASN | E | 245 | 14.785 | 44.534 | 38.437 | 1.00 | 21.91 | E | O |
| ATOM | 6273 | N | PHE | E | 246 | 13.517 | 43.456 | 36.923 | 1.00 | 22.16 | E | N |
| ATOM | 6274 | CA | PHE | E | 246 | 13.707 | 44.468 | 35.890 | 1.00 | 21.71 | E | C |
| ATOM | 6275 | CB | PHE | E | 246 | 13.224 | 43.953 | 34.532 | 1.00 | 20.57 | E | C |
| ATOM | 6276 | CG | PHE | E | 246 | 12.784 | 45.043 | 33.604 | 1.00 | 21.66 | E | C |
| ATOM | 6277 | CD1 | PHE | E | 246 | 11.439 | 45.335 | 33.445 | 1.00 | 20.79 | E | C |
| ATOM | 6278 | CD2 | PHE | E | 246 | 13.719 | 45.800 | 32.910 | 1.00 | 23.41 | E | C |
| ATOM | 6279 | CE1 | PHE | E | 246 | 11.029 | 46.364 | 32.612 | 1.00 | 19.43 | E | C |
| ATOM | 6280 | CE2 | PHE | E | 246 | 13.314 | 46.832 | 32.073 | 1.00 | 23.73 | E | C |
| ATOM | 6281 | CZ | PHE | E | 246 | 11.963 | 47.111 | 31.927 | 1.00 | 19.43 | E | C |
| ATOM | 6282 | C | PHE | E | 246 | 12.920 | 45.716 | 36.271 | 1.00 | 21.04 | E | C |
| ATOM | 6283 | O | PHE | E | 246 | 13.429 | 46.833 | 36.176 | 1.00 | 22.78 | E | O |
| ATOM | 6284 | N | LEU | E | 247 | 11.676 | 45.524 | 36.695 | 1.00 | 18.92 | E | N |
| ATOM | 6285 | CA | LEU | E | 247 | 10.833 | 46.644 | 37.088 | 1.00 | 19.42 | E | C |
| ATOM | 6286 | CB | LEU | E | 247 | 9.400 | 46.165 | 37.333 | 1.00 | 17.75 | E | C |
| ATOM | 6287 | CG | LEU | E | 247 | 8.619 | 45.791 | 36.065 | 1.00 | 17.15 | E | C |
| ATOM | 6288 | CD1 | LEU | E | 247 | 7.282 | 45.154 | 36.439 | 1.00 | 13.90 | E | C |
| ATOM | 6289 | CD2 | LEU | E | 247 | 8.405 | 47.042 | 35.219 | 1.00 | 12.74 | E | C |
| ATOM | 6290 | C | LEU | E | 247 | 11.395 | 47.314 | 38.342 | 1.00 | 20.60 | E | C |
| ATOM | 6291 | O | LEU | E | 247 | 11.330 | 48.532 | 38.483 | 1.00 | 20.84 | E | O |
| ATOM | 6292 | N | LEU | E | 248 | 11.954 | 46.517 | 39.247 | 1.00 | 20.88 | E | N |
| ATOM | 6293 | CA | LEU | E | 248 | 12.540 | 47.065 | 40.458 | 1.00 | 21.60 | E | C |
| ATOM | 6294 | CB | LEU | E | 248 | 13.095 | 45.941 | 41.337 | 1.00 | 23.02 | E | C |
| ATOM | 6295 | CG | LEU | E | 248 | 12.536 | 45.706 | 42.749 | 1.00 | 25.22 | E | C |
| ATOM | 6296 | CD1 | LEU | E | 248 | 11.160 | 46.322 | 42.917 | 1.00 | 25.83 | E | C |
| ATOM | 6297 | CD2 | LEU | E | 248 | 12.476 | 44.208 | 43.011 | 1.00 | 25.18 | E | C |
| ATOM | 6298 | C | LEU | E | 248 | 13.663 | 48.016 | 40.052 | 1.00 | 22.32 | E | C |
| ATOM | 6299 | O | LEU | E | 248 | 13.793 | 49.106 | 40.607 | 1.00 | 23.61 | E | O |
| ATOM | 6300 | N | ALA | E | 249 | 14.469 | 47.609 | 39.074 | 1.00 | 22.02 | E | N |
| ATOM | 6301 | CA | ALA | E | 249 | 15.573 | 48.446 | 38.603 | 1.00 | 20.88 | E | C |
| ATOM | 6302 | CB | ALA | E | 249 | 16.481 | 47.639 | 37.682 | 1.00 | 20.01 | E | C |
| ATOM | 6303 | C | ALA | E | 249 | 15.053 | 49.687 | 37.874 | 1.00 | 21.82 | E | C |
| ATOM | 6304 | O | ALA | E | 249 | 15.519 | 50.805 | 38.102 | 1.00 | 20.55 | E | O |
| ATOM | 6305 | N | LEU | E | 250 | 14.072 | 49.474 | 37.006 | 1.00 | 21.97 | E | N |
| ATOM | 6306 | CA | LEU | E | 250 | 13.480 | 50.548 | 36.227 | 1.00 | 21.82 | E | C |
| ATOM | 6307 | CB | LEU | E | 250 | 12.344 | 49.996 | 35.361 | 1.00 | 21.64 | E | C |
| ATOM | 6308 | CG | LEU | E | 250 | 11.726 | 50.976 | 34.360 | 1.00 | 20.44 | E | C |
| ATOM | 6309 | CD1 | LEU | E | 250 | 12.684 | 51.177 | 33.202 | 1.00 | 18.42 | E | C |
| ATOM | 6310 | CD2 | LEU | E | 250 | 10.388 | 50.446 | 33.872 | 1.00 | 19.71 | E | C |
| ATOM | 6311 | C | LEU | E | 250 | 12.962 | 51.712 | 37.066 | 1.00 | 22.28 | E | C |
| ATOM | 6312 | O | LEU | E | 250 | 13.341 | 52.853 | 36.834 | 1.00 | 22.25 | E | O |
| ATOM | 6313 | N | ILE | E | 251 | 12.097 | 51.434 | 38.038 | 1.00 | 23.52 | E | N |
| ATOM | 6314 | CA | ILE | E | 251 | 11.536 | 52.506 | 38.859 | 1.00 | 24.91 | E | C |
| ATOM | 6315 | CB | ILE | E | 251 | 10.442 | 51.987 | 39.830 | 1.00 | 24.63 | E | C |
| ATOM | 6316 | CG2 | ILE | E | 251 | 9.416 | 51.171 | 39.071 | 1.00 | 24.22 | E | C |
| ATOM | 6317 | CG1 | ILE | E | 251 | 11.072 | 51.148 | 40.941 | 1.00 | 25.17 | E | C |
| ATOM | 6318 | CD1 | ILE | E | 251 | 10.054 | 50.581 | 41.912 | 1.00 | 23.14 | E | C |
| ATOM | 6319 | C | ILE | E | 251 | 12.576 | 53.264 | 39.673 | 1.00 | 25.78 | E | C |
| ATOM | 6320 | O | ILE | E | 251 | 12.296 | 54.344 | 40.196 | 1.00 | 24.61 | E | O |
| ATOM | 6321 | N | ALA | E | 252 | 13.775 | 52.701 | 39.770 | 1.00 | 25.97 | E | N |
| ATOM | 6322 | CA | ALA | E | 252 | 14.848 | 53.336 | 40.520 | 1.00 | 26.47 | E | C |
| ATOM | 6323 | CB | ALA | E | 252 | 15.552 | 52.301 | 41.383 | 1.00 | 26.66 | E | C |
| ATOM | 6324 | C | ALA | E | 252 | 15.853 | 54.034 | 39.604 | 1.00 | 27.89 | E | C |
| ATOM | 6325 | O | ALA | E | 252 | 16.760 | 54.717 | 40.083 | 1.00 | 27.13 | E | O |
| ATOM | 6326 | N | GLN | E | 253 | 15.681 | 53.863 | 38.291 | 1.00 | 28.45 | E | N |
| ATOM | 6327 | CA | GLN | E | 253 | 16.567 | 54.466 | 37.290 | 1.00 | 28.31 | E | C |
| ATOM | 6328 | CB | GLN | E | 253 | 16.272 | 53.878 | 35.916 | 1.00 | 31.52 | E | C |
| ATOM | 6329 | CG | GLN | E | 253 | 17.488 | 53.341 | 35.199 | 1.00 | 35.12 | E | C |
| ATOM | 6330 | CD | GLN | E | 253 | 17.113 | 52.317 | 34.149 | 1.00 | 38.21 | E | C |
| ATOM | 6331 | OE1 | GLN | E | 253 | 17.399 | 51.130 | 34.296 | 1.00 | 40.47 | E | O |
| ATOM | 6332 | NE2 | GLN | E | 253 | 16.461 | 52.772 | 33.082 | 1.00 | 40.72 | E | N |
| ATOM | 6333 | C | GLN | E | 253 | 16.429 | 55.984 | 37.226 | 1.00 | 26.67 | E | C |
| ATOM | 6334 | O | GLN | E | 253 | 15.336 | 56.511 | 37.026 | 1.00 | 26.34 | E | O |
| ATOM | 6335 | N | GLY | E | 254 | 17.556 | 56.675 | 37.376 | 1.00 | 26.24 | E | N |
| ATOM | 6336 | CA | GLY | E | 254 | 17.571 | 58.129 | 37.363 | 1.00 | 24.04 | E | C |
| ATOM | 6337 | C | GLY | E | 254 | 16.894 | 58.790 | 36.181 | 1.00 | 23.83 | E | C |
| ATOM | 6338 | O | GLY | E | 254 | 15.954 | 59.561 | 36.362 | 1.00 | 25.05 | E | O |
| ATOM | 6339 | N | PRO | E | 255 | 17.361 | 58.525 | 34.955 | 1.00 | 23.22 | E | N |
| ATOM | 6340 | CD | PRO | E | 255 | 18.506 | 57.657 | 34.636 | 1.00 | 21.80 | E | C |
| ATOM | 6341 | CA | PRO | E | 255 | 16.775 | 59.111 | 33.743 | 1.00 | 22.57 | E | C |
| ATOM | 6342 | CB | PRO | E | 255 | 17.625 | 58.526 | 32.615 | 1.00 | 21.93 | E | C |
| ATOM | 6343 | CG | PRO | E | 255 | 18.909 | 58.138 | 33.282 | 1.00 | 21.25 | E | C |
| ATOM | 6344 | C | PRO | E | 255 | 15.289 | 58.801 | 33.569 | 1.00 | 21.04 | E | C |
| ATOM | 6345 | O | PRO | E | 255 | 14.529 | 59.644 | 33.103 | 1.00 | 21.75 | E | O |
| ATOM | 6346 | N | VAL | E | 256 | 14.877 | 57.591 | 33.938 | 1.00 | 20.98 | E | N |
| ATOM | 6347 | CA | VAL | E | 256 | 13.473 | 57.205 | 33.810 | 1.00 | 20.94 | E | C |
| ATOM | 6348 | CB | VAL | E | 256 | 13.278 | 55.696 | 34.076 | 1.00 | 19.46 | E | C |
| ATOM | 6349 | CG1 | VAL | E | 256 | 11.834 | 55.298 | 33.804 | 1.00 | 17.18 | E | C |
| ATOM | 6350 | CG2 | VAL | E | 256 | 14.227 | 54.888 | 33.203 | 1.00 | 20.46 | E | C |
| ATOM | 6351 | C | VAL | E | 256 | 12.628 | 58.001 | 34.798 | 1.00 | 22.84 | E | C |
| ATOM | 6352 | O | VAL | E | 256 | 11.501 | 58.405 | 34.494 | 1.00 | 24.28 | E | O |
| ATOM | 6353 | N | LYS | E | 257 | 13.187 | 58.228 | 35.984 | 1.00 | 22.89 | E | N |
| ATOM | 6354 | CA | LYS | E | 257 | 12.507 | 58.982 | 37.033 | 1.00 | 23.01 | E | C |
| ATOM | 6355 | CB | LYS | E | 257 | 13.349 | 58.977 | 38.319 | 1.00 | 24.18 | E | C |
| ATOM | 6356 | CG | LYS | E | 257 | 12.902 | 57.957 | 39.362 | 1.00 | 27.33 | E | C |
| ATOM | 6357 | CD | LYS | E | 257 | 14.087 | 57.344 | 40.093 | 1.00 | 29.99 | E | C |
| ATOM | 6358 | CE | LYS | E | 257 | 14.507 | 58.192 | 41.288 | 1.00 | 31.63 | E | C |
| ATOM | 6359 | NZ | LYS | E | 257 | 16.002 | 58.230 | 41.445 | 1.00 | 34.64 | E | N |
| ATOM | 6360 | C | LYS | E | 257 | 12.276 | 60.417 | 36.581 | 1.00 | 21.17 | E | C |
| ATOM | 6361 | O | LYS | E | 257 | 11.207 | 60.984 | 36.796 | 1.00 | 20.77 | E | O |
| ATOM | 6362 | N | THR | E | 258 | 13.288 | 60.998 | 35.946 | 1.00 | 21.88 | E | N |
| ATOM | 6363 | CA | THR | E | 258 | 13.206 | 62.371 | 35.463 | 1.00 | 21.13 | E | C |
| ATOM | 6364 | CB | THR | E | 258 | 14.583 | 62.871 | 35.008 | 1.00 | 23.18 | E | C |
| ATOM | 6365 | OG1 | THR | E | 258 | 15.453 | 62.923 | 36.143 | 1.00 | 26.47 | E | O |
| ATOM | 6366 | CG2 | THR | E | 258 | 14.480 | 64.262 | 34.405 | 1.00 | 21.77 | E | C |
| ATOM | 6367 | C | THR | E | 258 | 12.222 | 62.532 | 34.317 | 1.00 | 19.15 | E | C |
| ATOM | 6368 | O | THR | E | 258 | 11.386 | 63.431 | 34.327 | 1.00 | 19.73 | E | O |
| ATOM | 6369 | N | TYR | E | 259 | 12.323 | 61.657 | 33.327 | 1.00 | 17.50 | E | N |
| ATOM | 6370 | CA | TYR | E | 259 | 11.430 | 61.726 | 32.184 | 1.00 | 15.49 | E | C |
| ATOM | 6371 | CB | TYR | E | 259 | 11.755 | 60.602 | 31.196 | 1.00 | 15.18 | E | C |
| ATOM | 6372 | CG | TYR | E | 259 | 10.800 | 60.545 | 30.027 | 1.00 | 18.03 | E | C |
| ATOM | 6373 | CD1 | TYR | E | 259 | 9.765 | 59.609 | 29.992 | 1.00 | 17.98 | E | C |
| ATOM | 6374 | CE1 | TYR | E | 259 | 8.860 | 59.582 | 28.934 | 1.00 | 19.75 | E | C |
| ATOM | 6375 | CD2 | TYR | E | 259 | 10.908 | 61.452 | 28.973 | 1.00 | 17.97 | E | C |
| ATOM | 6376 | CE2 | TYR | E | 259 | 10.011 | 61.434 | 27.913 | 1.00 | 19.05 | E | C |
| ATOM | 6377 | CZ | TYR | E | 259 | 8.989 | 60.499 | 27.900 | 1.00 | 20.68 | E | C |
| ATOM | 6378 | OH | TYR | E | 259 | 8.086 | 60.496 | 26.863 | 1.00 | 21.60 | E | O |
| ATOM | 6379 | C | TYR | E | 259 | 9.979 | 61.615 | 32.642 | 1.00 | 14.69 | E | C |
| ATOM | 6380 | O | TYR | E | 259 | 9.148 | 62.477 | 32.346 | 1.00 | 12.96 | E | O |
| ATOM | 6381 | N | THR | E | 260 | 9.673 | 60.553 | 33.376 | 1.00 | 16.29 | E | N |
| ATOM | 6382 | CA | THR | E | 260 | 8.306 | 60.338 | 33.846 | 1.00 | 17.92 | E | C |
| ATOM | 6383 | CB | THR | E | 260 | 8.179 | 58.990 | 34.605 | 1.00 | 18.34 | E | C |
| ATOM | 6384 | OG1 | THR | E | 260 | 9.147 | 58.926 | 35.663 | 1.00 | 18.66 | E | O |
| ATOM | 6385 | CG2 | THR | E | 260 | 8.420 | 57.826 | 33.646 | 1.00 | 17.01 | E | C |
| ATOM | 6386 | C | THR | E | 260 | 7.810 | 61.483 | 34.727 | 1.00 | 18.40 | E | C |
| ATOM | 6387 | O | THR | E | 260 | 6.641 | 61.864 | 34.665 | 1.00 | 18.90 | E | O |
| ATOM | 6388 | N | HIS | E | 261 | 8.702 | 62.043 | 35.537 | 1.00 | 19.36 | E | N |
| ATOM | 6389 | CA | HIS | E | 261 | 8.328 | 63.144 | 36.414 | 1.00 | 18.29 | E | C |
| ATOM | 6390 | CB | HIS | E | 261 | 9.499 | 63.530 | 37.314 | 1.00 | 20.25 | E | C |
| ATOM | 6391 | CG | HIS | E | 261 | 9.163 | 64.604 | 38.299 | 1.00 | 20.79 | E | C |
| ATOM | 6392 | CD2 | HIS | E | 261 | 8.176 | 64.686 | 39.221 | 1.00 | 20.62 | E | C |
| ATOM | 6393 | ND1 | HIS | E | 261 | 9.860 | 65.791 | 38.375 | 1.00 | 21.51 | E | N |
| ATOM | 6394 | CE1 | HIS | E | 261 | 9.315 | 66.558 | 39.301 | 1.00 | 21.29 | E | C |
| ATOM | 6395 | NE2 | HIS | E | 261 | 8.292 | 65.911 | 39.828 | 1.00 | 19.87 | E | N |
| ATOM | 6396 | C | HIS | E | 261 | 7.905 | 64.346 | 35.589 | 1.00 | 18.21 | E | C |
| ATOM | 6397 | O | HIS | E | 261 | 6.890 | 64.985 | 35.872 | 1.00 | 17.76 | E | O |
| ATOM | 6398 | N | ARG | E | 262 | 8.695 | 64.652 | 34.568 | 1.00 | 18.43 | E | N |
| ATOM | 6399 | CA | ARG | E | 262 | 8.406 | 65.773 | 33.678 | 1.00 | 18.91 | E | C |
| ATOM | 6400 | CB | ARG | E | 262 | 9.547 | 65.931 | 32.667 | 1.00 | 21.93 | E | C |
| ATOM | 6401 | CG | ARG | E | 262 | 9.741 | 67.349 | 32.173 | 1.00 | 29.39 | E | C |
| ATOM | 6402 | CD | ARG | E | 262 | 10.797 | 67.420 | 31.073 | 1.00 | 35.97 | E | C |
| ATOM | 6403 | NE | ARG | E | 262 | 12.000 | 66.650 | 31.391 | 1.00 | 40.70 | E | N |
| ATOM | 6404 | CZ | ARG | E | 262 | 12.540 | 65.743 | 30.579 | 1.00 | 43.97 | E | C |
| ATOM | 6405 | NH1 | ARG | E | 262 | 11.980 | 65.494 | 29.400 | 1.00 | 44.28 | E | N |
| ATOM | 6406 | NH2 | ARG | E | 262 | 13.643 | 65.088 | 30.939 | 1.00 | 44.58 | E | N |
| ATOM | 6407 | C | ARG | E | 262 | 7.073 | 65.573 | 32.949 | 1.00 | 14.63 | E | C |
| ATOM | 6408 | O | ARG | E | 262 | 6.254 | 66.489 | 32.877 | 1.00 | 15.00 | E | O |
| ATOM | 6409 | N | ARG | E | 263 | 6.845 | 64.373 | 32.422 | 1.00 | 13.64 | E | N |
| ATOM | 6410 | CA | ARG | E | 263 | 5.603 | 64.098 | 31.707 | 1.00 | 11.51 | E | C |
| ATOM | 6411 | CB | ARG | E | 263 | 5.634 | 62.687 | 31.128 | 1.00 | 10.05 | E | C |
| ATOM | 6412 | CG | ARG | E | 263 | 6.736 | 62.434 | 30.085 | 1.00 | 10.14 | E | C |
| ATOM | 6413 | CD | ARG | E | 263 | 6.852 | 63.544 | 29.031 | 1.00 | 8.54 | E | C |
| ATOM | 6414 | NE | ARG | E | 263 | 5.580 | 63.846 | 28.383 | 1.00 | 9.36 | E | N |
| ATOM | 6415 | CZ | ARG | E | 263 | 5.318 | 64.989 | 27.751 | 1.00 | 9.81 | E | C |
| ATOM | 6416 | NH1 | ARG | E | 263 | 6.244 | 65.932 | 27.684 | 1.00 | 8.80 | E | N |
| ATOM | 6417 | NH2 | ARG | E | 263 | 4.126 | 65.201 | 27.203 | 1.00 | 6.84 | E | N |
| ATOM | 6418 | C | ARG | E | 263 | 4.377 | 64.280 | 32.607 | 1.00 | 12.69 | E | C |
| ATOM | 6419 | O | ARG | E | 263 | 3.345 | 64.809 | 32.174 | 1.00 | 13.24 | E | O |
| ATOM | 6420 | N | LEU | E | 264 | 4.497 | 63.862 | 33.866 | 1.00 | 11.46 | E | N |
| ATOM | 6421 | CA | LEU | E | 264 | 3.401 | 64.001 | 34.823 | 1.00 | 10.95 | E | C |
| ATOM | 6422 | CB | LEU | E | 264 | 3.741 | 63.263 | 36.123 | 1.00 | 9.43 | E | C |
| ATOM | 6423 | CG | LEU | E | 264 | 3.704 | 61.736 | 35.993 | 1.00 | 6.05 | E | C |
| ATOM | 6424 | CD1 | LEU | E | 264 | 4.435 | 61.084 | 37.158 | 1.00 | 7.55 | E | C |
| ATOM | 6425 | CD2 | LEU | E | 264 | 2.260 | 61.265 | 35.935 | 1.00 | 5.00 | E | C |
| ATOM | 6426 | C | LEU | E | 264 | 3.109 | 65.475 | 35.099 | 1.00 | 10.58 | E | C |
| ATOM | 6427 | O | LEU | E | 264 | 1.956 | 65.877 | 35.250 | 1.00 | 8.45 | E | O |
| ATOM | 6428 | N | LYS | E | 265 | 4.162 | 66.284 | 35.155 | 1.00 | 14.55 | E | N |
| ATOM | 6429 | CA | LYS | E | 265 | 4.006 | 67.718 | 35.373 | 1.00 | 14.61 | E | C |
| ATOM | 6430 | CB | LYS | E | 265 | 5.372 | 68.394 | 35.464 | 1.00 | 17.84 | E | C |
| ATOM | 6431 | CG | LYS | E | 265 | 5.983 | 68.396 | 36.862 | 1.00 | 23.01 | E | C |
| ATOM | 6432 | CD | LYS | E | 265 | 7.501 | 68.578 | 36.814 | 1.00 | 27.67 | E | C |
| ATOM | 6433 | CE | LYS | E | 265 | 7.893 | 70.041 | 36.643 | 1.00 | 31.25 | E | C |
| ATOM | 6434 | NZ | LYS | E | 265 | 9.261 | 70.222 | 36.044 | 1.00 | 35.15 | E | N |
| ATOM | 6435 | C | LYS | E | 265 | 3.238 | 68.277 | 34.178 | 1.00 | 15.99 | E | C |
| ATOM | 6436 | O | LYS | E | 265 | 2.342 | 69.111 | 34.334 | 1.00 | 17.97 | E | O |
| ATOM | 6437 | N | PHE | E | 266 | 3.583 | 67.810 | 32.977 | 1.00 | 15.88 | E | N |
| ATOM | 6438 | CA | PHE | E | 266 | 2.901 | 68.279 | 31.776 | 1.00 | 14.70 | E | C |
| ATOM | 6439 | CB | PHE | E | 266 | 3.563 | 67.719 | 30.508 | 1.00 | 14.32 | E | C |
| ATOM | 6440 | CG | PHE | E | 266 | 2.882 | 68.158 | 29.236 | 1.00 | 14.09 | E | C |
| ATOM | 6441 | CD1 | PHE | E | 266 | 3.111 | 69.428 | 28.708 | 1.00 | 13.50 | E | C |
| ATOM | 6442 | CD2 | PHE | E | 266 | 1.957 | 67.330 | 28.602 | 1.00 | 13.04 | E | C |
| ATOM | 6443 | CE1 | PHE | E | 266 | 2.418 | 69.870 | 27.571 | 1.00 | 13.30 | E | C |
| ATOM | 6444 | CE2 | PHE | E | 266 | 1.262 | 67.763 | 27.464 | 1.00 | 12.02 | E | C |
| ATOM | 6445 | CZ | PHE | E | 266 | 1.491 | 69.033 | 26.952 | 1.00 | 11.89 | E | C |
| ATOM | 6446 | C | PHE | E | 266 | 1.430 | 67.878 | 31.808 | 1.00 | 12.87 | E | C |
| ATOM | 6447 | O | PHE | E | 266 | 0.551 | 68.689 | 31.507 | 1.00 | 14.02 | E | O |
| ATOM | 6448 | N | LEU | E | 267 | 1.166 | 66.625 | 32.168 | 1.00 | 12.41 | E | N |
| ATOM | 6449 | CA | LEU | E | 267 | −0.205 | 66.121 | 32.245 | 1.00 | 11.96 | E | C |
| ATOM | 6450 | CB | LEU | E | 267 | −0.191 | 64.687 | 32.778 | 1.00 | 13.87 | E | C |
| ATOM | 6451 | CG | LEU | E | 267 | −0.443 | 63.468 | 31.876 | 1.00 | 15.20 | E | C |
| ATOM | 6452 | CD1 | LEU | E | 267 | −0.254 | 63.811 | 30.406 | 1.00 | 13.09 | E | C |
| ATOM | 6453 | CD2 | LEU | E | 267 | 0.498 | 62.358 | 32.296 | 1.00 | 12.50 | E | C |
| ATOM | 6454 | C | LEU | E | 267 | −1.047 | 67.012 | 33.169 | 1.00 | 12.50 | E | C |
| ATOM | 6455 | O | LEU | E | 267 | −2.229 | 67.270 | 32.917 | 1.00 | 11.70 | E | O |
| ATOM | 6456 | N | SER | E | 268 | −0.415 | 67.489 | 34.237 | 1.00 | 12.60 | E | N |
| ATOM | 6457 | CA | SER | E | 268 | −1.066 | 68.346 | 35.222 | 1.00 | 10.88 | E | C |
| ATOM | 6458 | CB | SER | E | 268 | −0.171 | 68.462 | 36.459 | 1.00 | 12.97 | E | C |
| ATOM | 6459 | OG | SER | E | 268 | −0.806 | 69.199 | 37.487 | 1.00 | 14.03 | E | O |
| ATOM | 6460 | C | SER | E | 268 | −1.358 | 69.736 | 34.667 | 1.00 | 10.80 | E | C |
| ATOM | 6461 | O | SER | E | 268 | −2.501 | 70.198 | 34.707 | 1.00 | 10.50 | E | O |
| ATOM | 6462 | N | SER | E | 269 | −0.329 | 70.414 | 34.159 | 1.00 | 11.08 | E | N |
| ATOM | 6463 | CA | SER | E | 269 | −0.516 | 71.753 | 33.589 | 1.00 | 11.58 | E | C |
| ATOM | 6464 | CB | SER | E | 269 | 0.816 | 72.328 | 33.126 | 1.00 | 12.03 | E | C |
| ATOM | 6465 | OG | SER | E | 269 | 1.732 | 72.450 | 34.194 | 1.00 | 10.98 | E | O |
| ATOM | 6466 | C | SER | E | 269 | −1.486 | 71.741 | 32.405 | 1.00 | 11.80 | E | C |
| ATOM | 6467 | O | SER | E | 269 | −2.321 | 72.640 | 32.265 | 1.00 | 12.09 | E | O |
| ATOM | 6468 | N | LYS | E | 270 | −1.379 | 70.729 | 31.545 | 1.00 | 12.14 | E | N |
| ATOM | 6469 | CA | LYS | E | 270 | −2.277 | 70.655 | 30.406 | 1.00 | 12.57 | E | C |
| ATOM | 6470 | CB | LYS | E | 270 | −2.000 | 69.404 | 29.561 | 1.00 | 12.57 | E | C |
| ATOM | 6471 | CG | LYS | E | 270 | −2.411 | 69.574 | 28.090 | 1.00 | 9.93 | E | C |
| ATOM | 6472 | CD | LYS | E | 270 | −2.519 | 68.246 | 27.358 | 1.00 | 8.42 | E | C |
| ATOM | 6473 | CE | LYS | E | 270 | −3.331 | 68.382 | 26.070 | 1.00 | 9.10 | E | C |
| ATOM | 6474 | NZ | LYS | E | 270 | −3.501 | 67.070 | 25.369 | 1.00 | 10.04 | E | N |
| ATOM | 6475 | C | LYS | E | 270 | −3.733 | 70.662 | 30.846 | 1.00 | 13.95 | E | C |
| ATOM | 6476 | O | LYS | E | 270 | −4.553 | 71.365 | 30.264 | 1.00 | 14.74 | E | O |
| ATOM | 6477 | N | PHE | E | 271 | −4.068 | 69.883 | 31.871 | 1.00 | 14.73 | E | N |
| ATOM | 6478 | CA | PHE | E | 271 | −5.449 | 69.848 | 32.329 | 1.00 | 14.65 | E | C |
| ATOM | 6479 | CB | PHE | E | 271 | −5.639 | 68.827 | 33.453 | 1.00 | 14.10 | E | C |
| ATOM | 6480 | CG | PHE | E | 271 | −7.075 | 68.635 | 33.834 | 1.00 | 13.61 | E | C |
| ATOM | 6481 | CD1 | PHE | E | 271 | −7.911 | 67.831 | 33.058 | 1.00 | 12.39 | E | C |
| ATOM | 6482 | CD2 | PHE | E | 271 | −7.615 | 69.303 | 34.937 | 1.00 | 13.18 | E | C |
| ATOM | 6483 | CE1 | PHE | E | 271 | −9.268 | 67.697 | 33.369 | 1.00 | 14.24 | E | C |
| ATOM | 6484 | CE2 | PHE | E | 271 | −8.971 | 69.178 | 35.260 | 1.00 | 11.80 | E | C |
| ATOM | 6485 | CZ | PHE | E | 271 | −9.804 | 68.372 | 34.473 | 1.00 | 11.60 | E | C |
| ATOM | 6486 | C | PHE | E | 271 | −5.922 | 71.212 | 32.817 | 1.00 | 17.63 | E | C |
| ATOM | 6487 | O | PHE | E | 271 | −7.066 | 71.606 | 32.582 | 1.00 | 19.61 | E | O |
| ATOM | 6488 | N | GLN | E | 272 | −5.040 | 71.934 | 33.496 | 1.00 | 17.85 | E | N |
| ATOM | 6489 | CA | GLN | E | 272 | −5.375 | 73.251 | 34.020 | 1.00 | 18.16 | E | C |
| ATOM | 6490 | CB | GLN | E | 272 | −4.204 | 73.799 | 34.830 | 1.00 | 20.56 | E | C |
| ATOM | 6491 | CG | GLN | E | 272 | −4.445 | 73.783 | 36.326 | 1.00 | 29.05 | E | C |
| ATOM | 6492 | CD | GLN | E | 272 | −3.611 | 72.738 | 37.045 | 1.00 | 30.98 | E | C |
| ATOM | 6493 | OE1 | GLN | E | 272 | −2.488 | 73.012 | 37.483 | 1.00 | 32.70 | E | O |
| ATOM | 6494 | NE2 | GLN | E | 272 | −4.158 | 71.530 | 37.174 | 1.00 | 31.83 | E | N |
| ATOM | 6495 | C | GLN | E | 272 | −5.731 | 74.232 | 32.910 | 1.00 | 16.59 | E | C |
| ATOM | 6496 | O | GLN | E | 272 | −6.691 | 74.996 | 33.026 | 1.00 | 15.47 | E | O |
| ATOM | 6497 | N | VAL | E | 273 | −4.946 | 74.226 | 31.837 | 1.00 | 14.34 | E | N |
| ATOM | 6498 | CA | VAL | E | 273 | −5.221 | 75.124 | 30.732 | 1.00 | 13.09 | E | C |
| ATOM | 6499 | CB | VAL | E | 273 | −4.043 | 75.152 | 29.740 | 1.00 | 13.71 | E | C |
| ATOM | 6500 | CG1 | VAL | E | 273 | −4.393 | 76.003 | 28.529 | 1.00 | 13.96 | E | C |
| ATOM | 6501 | CG2 | VAL | E | 273 | −2.811 | 75.707 | 30.434 | 1.00 | 11.71 | E | C |
| ATOM | 6502 | C | VAL | E | 273 | −6.504 | 74.672 | 30.038 | 1.00 | 13.03 | E | C |
| ATOM | 6503 | O | VAL | E | 273 | −7.338 | 75.495 | 29.663 | 1.00 | 13.71 | E | O |
| ATOM | 6504 | N | HIS | E | 274 | −6.674 | 73.361 | 29.888 | 1.00 | 12.93 | E | N |
| ATOM | 6505 | CA | HIS | E | 274 | −7.879 | 72.829 | 29.253 | 1.00 | 14.62 | E | C |
| ATOM | 6506 | CB | HIS | E | 274 | −7.838 | 71.299 | 29.214 | 1.00 | 13.47 | E | C |
| ATOM | 6507 | CG | HIS | E | 274 | −9.169 | 70.663 | 28.935 | 1.00 | 13.74 | E | C |
| ATOM | 6508 | CD2 | HIS | E | 274 | −10.009 | 69.963 | 29.735 | 1.00 | 14.60 | E | C |
| ATOM | 6509 | ND1 | HIS | E | 274 | −9.781 | 70.725 | 27.703 | 1.00 | 13.60 | E | N |
| ATOM | 6510 | CE1 | HIS | E | 274 | −10.940 | 70.093 | 27.753 | 1.00 | 13.01 | E | C |
| ATOM | 6511 | NE2 | HIS | E | 274 | −11.102 | 69.621 | 28.976 | 1.00 | 13.70 | E | N |
| ATOM | 6512 | C | HIS | E | 274 | −9.118 | 73.278 | 30.016 | 1.00 | 16.75 | E | C |
| ATOM | 6513 | O | HIS | E | 274 | −10.082 | 73.777 | 29.431 | 1.00 | 15.44 | E | O |
| ATOM | 6514 | N | GLN | E | 275 | −9.088 | 73.102 | 31.333 | 1.00 | 20.68 | E | N |
| ATOM | 6515 | CA | GLN | E | 275 | −10.224 | 73.481 | 32.165 | 1.00 | 24.82 | E | C |
| ATOM | 6516 | CB | GLN | E | 275 | −10.003 | 73.031 | 33.610 | 1.00 | 27.38 | E | C |
| ATOM | 6517 | CG | GLN | E | 275 | −11.008 | 71.985 | 34.075 | 1.00 | 36.13 | E | C |
| ATOM | 6518 | CD | GLN | E | 275 | −11.081 | 71.875 | 35.597 | 1.00 | 41.86 | E | C |
| ATOM | 6519 | OE1 | GLN | E | 275 | −10.459 | 72.664 | 36.325 | 1.00 | 42.62 | E | O |
| ATOM | 6520 | NE2 | GLN | E | 275 | −11.842 | 70.893 | 36.086 | 1.00 | 42.20 | E | N |
| ATOM | 6521 | C | GLN | E | 275 | −10.519 | 74.974 | 32.136 | 1.00 | 24.09 | E | C |
| ATOM | 6522 | O | GLN | E | 275 | −11.674 | 75.381 | 32.028 | 1.00 | 24.51 | E | O |
| ATOM | 6523 | N | MET | E | 276 | −9.485 | 75.798 | 32.226 | 1.00 | 23.97 | E | N |
| ATOM | 6524 | CA | MET | E | 276 | −9.718 | 77.227 | 32.215 | 1.00 | 25.02 | E | C |
| ATOM | 6525 | CB | MET | E | 276 | −8.464 | 77.975 | 32.664 | 1.00 | 28.21 | E | C |
| ATOM | 6526 | CG | MET | E | 276 | −7.429 | 78.205 | 31.596 | 1.00 | 31.58 | E | C |
| ATOM | 6527 | SD | MET | E | 276 | −6.035 | 79.100 | 32.292 | 1.00 | 39.02 | E | S |
| ATOM | 6528 | CE | MET | E | 276 | −5.203 | 77.810 | 33.254 | 1.00 | 34.26 | E | C |
| ATOM | 6529 | C | MET | E | 276 | −10.180 | 77.711 | 30.850 | 1.00 | 24.05 | E | C |
| ATOM | 6530 | O | MET | E | 276 | −10.871 | 78.721 | 30.746 | 1.00 | 25.40 | E | O |
| ATOM | 6531 | N | LEU | E | 277 | −9.827 | 76.978 | 29.802 | 1.00 | 22.40 | E | N |
| ATOM | 6532 | CA | LEU | E | 277 | −10.228 | 77.351 | 28.447 | 1.00 | 21.26 | E | C |
| ATOM | 6533 | CB | LEU | E | 277 | −9.147 | 76.913 | 27.452 | 1.00 | 20.59 | E | C |
| ATOM | 6534 | CG | LEU | E | 277 | −8.219 | 77.900 | 26.737 | 1.00 | 20.01 | E | C |
| ATOM | 6535 | CD1 | LEU | E | 277 | −7.986 | 79.167 | 27.554 | 1.00 | 18.50 | E | C |
| ATOM | 6536 | CD2 | LEU | E | 277 | −6.910 | 77.185 | 26.480 | 1.00 | 20.26 | E | C |
| ATOM | 6537 | C | LEU | E | 277 | −11.569 | 76.743 | 27.997 | 1.00 | 20.90 | E | C |
| ATOM | 6538 | O | LEU | E | 277 | −12.314 | 77.371 | 27.239 | 1.00 | 20.49 | E | O |
| ATOM | 6539 | N | ASN | E | 278 | −11.884 | 75.538 | 28.476 | 1.00 | 18.18 | E | N |
| ATOM | 6540 | CA | ASN | E | 278 | −13.090 | 74.842 | 28.033 | 1.00 | 16.08 | E | C |
| ATOM | 6541 | CB | ASN | E | 278 | −12.667 | 73.675 | 27.136 | 1.00 | 14.60 | E | C |
| ATOM | 6542 | CG | ASN | E | 278 | −11.701 | 74.101 | 26.047 | 1.00 | 13.99 | E | C |
| ATOM | 6543 | OD1 | ASN | E | 278 | −10.548 | 73.653 | 25.995 | 1.00 | 15.54 | E | O |
| ATOM | 6544 | ND2 | ASN | E | 278 | −12.166 | 74.975 | 25.167 | 1.00 | 12.51 | E | N |
| ATOM | 6545 | C | ASN | E | 278 | −14.117 | 74.324 | 29.043 | 1.00 | 16.49 | E | C |
| ATOM | 6546 | O | ASN | E | 278 | −15.063 | 73.631 | 28.655 | 1.00 | 15.76 | E | O |
| ATOM | 6547 | N | GLU | E | 279 | −13.961 | 74.647 | 30.323 | 1.00 | 18.32 | E | N |
| ATOM | 6548 | CA | GLU | E | 279 | −14.916 | 74.165 | 31.320 | 1.00 | 18.50 | E | C |
| ATOM | 6549 | CB | GLU | E | 279 | −14.496 | 74.610 | 32.722 | 1.00 | 19.81 | E | C |
| ATOM | 6550 | CG | GLU | E | 279 | −14.348 | 76.108 | 32.877 | 1.00 | 23.41 | E | C |
| ATOM | 6551 | CD | GLU | E | 279 | −14.049 | 76.505 | 34.303 | 1.00 | 27.30 | E | C |
| ATOM | 6552 | OE1 | GLU | E | 279 | −14.499 | 75.782 | 35.216 | 1.00 | 29.99 | E | O |
| ATOM | 6553 | OE2 | GLU | E | 279 | −13.369 | 77.534 | 34.511 | 1.00 | 27.50 | E | O |
| ATOM | 6554 | C | GLU | E | 279 | −16.352 | 74.613 | 31.035 | 1.00 | 16.97 | E | C |
| ATOM | 6555 | O | GLU | E | 279 | −17.294 | 73.846 | 31.228 | 1.00 | 16.75 | E | O |
| ATOM | 6556 | N | MET | E | 280 | −16.526 | 75.847 | 30.574 | 1.00 | 17.48 | E | N |
| ATOM | 6557 | CA | MET | E | 280 | −17.869 | 76.350 | 30.274 | 1.00 | 19.06 | E | C |
| ATOM | 6558 | CB | MET | E | 280 | −17.816 | 77.842 | 29.935 | 1.00 | 23.36 | E | C |
| ATOM | 6559 | CG | MET | E | 280 | −17.608 | 78.769 | 31.137 | 1.00 | 32.24 | E | C |
| ATOM | 6560 | SD | MET | E | 280 | −18.587 | 78.313 | 32.624 | 1.00 | 42.97 | E | S |
| ATOM | 6561 | CE | MET | E | 280 | −20.141 | 79.183 | 32.296 | 1.00 | 40.50 | E | C |
| ATOM | 6562 | C | MET | E | 280 | −18.469 | 75.579 | 29.102 | 1.00 | 18.26 | E | C |
| ATOM | 6563 | O | MET | E | 280 | −19.686 | 75.414 | 28.995 | 1.00 | 17.68 | E | O |
| ATOM | 6564 | N | ASP | E | 281 | −17.595 | 75.098 | 28.229 | 1.00 | 17.37 | E | N |
| ATOM | 6565 | CA | ASP | E | 281 | −18.007 | 74.337 | 27.060 | 1.00 | 17.88 | E | C |
| ATOM | 6566 | CB | ASP | E | 281 | −16.873 | 74.341 | 26.038 | 1.00 | 19.17 | E | C |
| ATOM | 6567 | CG | ASP | E | 281 | −16.593 | 75.741 | 25.513 | 1.00 | 21.62 | E | C |
| ATOM | 6568 | OD1 | ASP | E | 281 | −15.498 | 76.286 | 25.778 | 1.00 | 23.61 | E | O |
| ATOM | 6569 | OD2 | ASP | E | 281 | −17.488 | 76.306 | 24.843 | 1.00 | 23.80 | E | O |
| ATOM | 6570 | C | ASP | E | 281 | −18.411 | 72.919 | 27.433 | 1.00 | 17.59 | E | C |
| ATOM | 6571 | O | ASP | E | 281 | −19.375 | 72.376 | 26.885 | 1.00 | 14.66 | E | O |
| ATOM | 6572 | N | GLU | E | 282 | −17.674 | 72.314 | 28.361 | 1.00 | 17.35 | E | N |
| ATOM | 6573 | CA | GLU | E | 282 | −18.030 | 70.973 | 28.815 | 1.00 | 16.43 | E | C |
| ATOM | 6574 | CB | GLU | E | 282 | −16.958 | 70.421 | 29.754 | 1.00 | 15.60 | E | C |
| ATOM | 6575 | CG | GLU | E | 282 | −15.654 | 70.107 | 29.053 | 1.00 | 13.12 | E | C |
| ATOM | 6576 | CD | GLU | E | 282 | −14.567 | 69.742 | 30.015 | 1.00 | 13.94 | E | C |
| ATOM | 6577 | OE1 | GLU | E | 282 | −14.543 | 70.326 | 31.114 | 1.00 | 12.06 | E | O |
| ATOM | 6578 | OE2 | GLU | E | 282 | −13.735 | 68.872 | 29.682 | 1.00 | 14.29 | E | O |
| ATOM | 6579 | C | GLU | E | 282 | −19.367 | 71.096 | 29.548 | 1.00 | 15.91 | E | C |
| ATOM | 6580 | O | GLU | E | 282 | −20.261 | 70.268 | 29.373 | 1.00 | 16.56 | E | O |
| ATOM | 6581 | N | LEU | E | 283 | −19.508 | 72.151 | 30.347 | 1.00 | 14.64 | E | N |
| ATOM | 6582 | CA | LEU | E | 283 | −20.743 | 72.381 | 31.089 | 1.00 | 15.88 | E | C |
| ATOM | 6583 | CB | LEU | E | 283 | −20.636 | 73.664 | 31.918 | 1.00 | 16.18 | E | C |
| ATOM | 6584 | CG | LEU | E | 283 | −21.377 | 73.782 | 33.266 | 1.00 | 19.79 | E | C |
| ATOM | 6585 | CD1 | LEU | E | 283 | −21.940 | 75.192 | 33.398 | 1.00 | 17.85 | E | C |
| ATOM | 6586 | CD2 | LEU | E | 283 | −22.495 | 72.749 | 33.394 | 1.00 | 17.61 | E | C |
| ATOM | 6587 | C | LEU | E | 283 | −21.931 | 72.497 | 30.138 | 1.00 | 17.04 | E | C |
| ATOM | 6588 | O | LEU | E | 283 | −23.007 | 71.938 | 30.396 | 1.00 | 16.83 | E | O |
| ATOM | 6589 | N | LYS | E | 284 | −21.741 | 73.238 | 29.048 | 1.00 | 17.80 | E | N |
| ATOM | 6590 | CA | LYS | E | 284 | −22.802 | 73.418 | 28.064 | 1.00 | 16.83 | E | C |
| ATOM | 6591 | CB | LYS | E | 284 | −22.288 | 74.256 | 26.889 | 1.00 | 20.60 | E | C |
| ATOM | 6592 | CG | LYS | E | 284 | −23.351 | 74.611 | 25.856 | 1.00 | 22.44 | E | C |
| ATOM | 6593 | CD | LYS | E | 284 | −22.742 | 75.329 | 24.656 | 1.00 | 27.52 | E | C |
| ATOM | 6594 | CE | LYS | E | 284 | −23.815 | 75.795 | 23.671 | 1.00 | 30.96 | E | C |
| ATOM | 6595 | NZ | LYS | E | 284 | −23.250 | 76.575 | 22.521 | 1.00 | 33.78 | E | N |
| ATOM | 6596 | C | LYS | E | 284 | −23.333 | 72.071 | 27.563 | 1.00 | 15.42 | E | C |
| ATOM | 6597 | O | LYS | E | 284 | −24.537 | 71.909 | 27.371 | 1.00 | 15.79 | E | O |
| ATOM | 6598 | N | GLU | E | 285 | −22.444 | 71.102 | 27.362 | 1.00 | 14.57 | E | N |
| ATOM | 6599 | CA | GLU | E | 285 | −22.869 | 69.781 | 26.894 | 1.00 | 15.47 | E | C |
| ATOM | 6600 | CB | GLU | E | 285 | −21.665 | 68.852 | 26.690 | 1.00 | 15.08 | E | C |
| ATOM | 6601 | CG | GLU | E | 285 | −20.807 | 69.156 | 25.471 | 1.00 | 15.10 | E | C |
| ATOM | 6602 | CD | GLU | E | 285 | −19.821 | 68.033 | 25.148 | 1.00 | 15.69 | E | C |
| ATOM | 6603 | OE1 | GLU | E | 285 | −20.273 | 66.917 | 24.803 | 1.00 | 14.66 | E | O |
| ATOM | 6604 | OE2 | GLU | E | 285 | −18.593 | 68.266 | 25.241 | 1.00 | 15.37 | E | O |
| ATOM | 6605 | C | GLU | E | 285 | −23.820 | 69.130 | 27.894 | 1.00 | 17.50 | E | C |
| ATOM | 6606 | O | GLU | E | 285 | −24.873 | 68.613 | 27.515 | 1.00 | 17.39 | E | O |
| ATOM | 6607 | N | LEU | E | 286 | −23.446 | 69.152 | 29.174 | 1.00 | 19.22 | E | N |
| ATOM | 6608 | CA | LEU | E | 286 | −24.276 | 68.549 | 30.216 | 1.00 | 19.49 | E | C |
| ATOM | 6609 | CB | LEU | E | 286 | −23.556 | 68.572 | 31.575 | 1.00 | 20.23 | E | C |
| ATOM | 6610 | CG | LEU | E | 286 | −22.094 | 68.122 | 31.741 | 1.00 | 22.37 | E | C |
| ATOM | 6611 | CD1 | LEU | E | 286 | −21.994 | 67.338 | 33.035 | 1.00 | 23.35 | E | C |
| ATOM | 6612 | CD2 | LEU | E | 286 | −21.605 | 67.278 | 30.575 | 1.00 | 20.15 | E | C |
| ATOM | 6613 | C | LEU | E | 286 | −25.615 | 69.266 | 30.341 | 1.00 | 18.63 | E | C |
| ATOM | 6614 | O | LEU | E | 286 | −26.656 | 68.627 | 30.476 | 1.00 | 20.34 | E | O |
| ATOM | 6615 | N | LYS | E | 287 | −25.586 | 70.594 | 30.300 | 1.00 | 19.82 | E | N |
| ATOM | 6616 | CA | LYS | E | 287 | −26.810 | 71.386 | 30.404 | 1.00 | 21.17 | E | C |
| ATOM | 6617 | CB | LYS | E | 287 | −26.486 | 72.877 | 30.341 | 1.00 | 21.52 | E | C |
| ATOM | 6618 | CG | LYS | E | 287 | −26.122 | 73.505 | 31.667 | 1.00 | 23.60 | E | C |
| ATOM | 6619 | CD | LYS | E | 287 | −25.329 | 74.778 | 31.449 | 1.00 | 25.31 | E | C |
| ATOM | 6620 | CE | LYS | E | 287 | −25.968 | 75.966 | 32.150 | 1.00 | 25.91 | E | C |
| ATOM | 6621 | NZ | LYS | E | 287 | −24.974 | 77.059 | 32.387 | 1.00 | 27.98 | E | N |
| ATOM | 6622 | C | LYS | E | 287 | −27.768 | 71.045 | 29.271 | 1.00 | 21.31 | E | C |
| ATOM | 6623 | O | LYS | E | 287 | −28.982 | 70.992 | 29.464 | 1.00 | 22.68 | E | O |
| ATOM | 6624 | N | ASN | E | 288 | −27.216 | 70.813 | 28.086 | 1.00 | 22.77 | E | N |
| ATOM | 6625 | CA | ASN | E | 288 | −28.031 | 70.491 | 26.919 | 1.00 | 23.88 | E | C |
| ATOM | 6626 | CB | ASN | E | 288 | −27.339 | 70.974 | 25.644 | 1.00 | 23.56 | E | C |
| ATOM | 6627 | CG | ASN | E | 288 | −27.441 | 72.473 | 25.469 | 1.00 | 22.25 | E | C |
| ATOM | 6628 | OD1 | ASN | E | 288 | −28.486 | 73.067 | 25.723 | 1.00 | 21.29 | E | O |
| ATOM | 6629 | ND2 | ASN | E | 288 | −26.353 | 73.094 | 25.038 | 1.00 | 25.80 | E | N |
| ATOM | 6630 | C | ASN | E | 288 | −28.348 | 69.007 | 26.810 | 1.00 | 24.66 | E | C |
| ATOM | 6631 | O | ASN | E | 288 | −28.875 | 68.547 | 25.803 | 1.00 | 24.28 | E | O |
| ATOM | 6632 | N | ASN | E | 289 | −28.022 | 68.267 | 27.861 | 1.00 | 26.10 | E | N |
| ATOM | 6633 | CA | ASN | E | 289 | −28.288 | 66.836 | 27.921 | 1.00 | 27.31 | E | C |
| ATOM | 6634 | CB | ASN | E | 289 | −27.047 | 66.112 | 28.449 | 1.00 | 25.57 | E | C |
| ATOM | 6635 | CG | ASN | E | 289 | −27.189 | 64.615 | 28.408 | 1.00 | 24.07 | E | C |
| ATOM | 6636 | OD1 | ASN | E | 289 | −27.827 | 64.066 | 27.513 | 1.00 | 20.93 | E | O |
| ATOM | 6637 | ND2 | ASN | E | 289 | −26.594 | 63.939 | 29.383 | 1.00 | 24.78 | E | N |
| ATOM | 6638 | C | ASN | E | 289 | −29.467 | 66.676 | 28.888 | 1.00 | 29.86 | E | C |
| ATOM | 6639 | O | ASN | E | 289 | −29.280 | 66.594 | 30.105 | 1.00 | 32.70 | E | O |
| ATOM | 6640 | N | PRO | E | 290 | −30.701 | 66.643 | 28.355 | 1.00 | 31.61 | E | N |
| ATOM | 6641 | CD | PRO | E | 290 | −31.014 | 66.714 | 26.916 | 1.00 | 30.10 | E | C |
| ATOM | 6642 | CA | PRO | E | 290 | −31.919 | 66.505 | 29.168 | 1.00 | 32.97 | E | C |
| ATOM | 6643 | CB | PRO | E | 290 | −33.035 | 66.853 | 28.191 | 1.00 | 32.48 | E | C |
| ATOM | 6644 | CG | PRO | E | 290 | −32.485 | 66.399 | 26.870 | 1.00 | 32.34 | E | C |
| ATOM | 6645 | C | PRO | E | 290 | −32.124 | 65.126 | 29.781 | 1.00 | 33.64 | E | C |
| ATOM | 6646 | O | PRO | E | 290 | −32.954 | 64.944 | 30.673 | 1.00 | 33.05 | E | O |
| ATOM | 6647 | N | HIS | E | 291 | −31.359 | 64.158 | 29.299 | 1.00 | 34.54 | E | N |
| ATOM | 6648 | CA | HIS | E | 291 | −31.478 | 62.794 | 29.789 | 1.00 | 37.80 | E | C |
| ATOM | 6649 | CB | HIS | E | 291 | −30.848 | 61.828 | 28.782 | 1.00 | 40.57 | E | C |
| ATOM | 6650 | CG | HIS | E | 291 | −31.441 | 61.922 | 27.413 | 1.00 | 45.80 | E | C |
| ATOM | 6651 | CD2 | HIS | E | 291 | −32.408 | 61.192 | 26.809 | 1.00 | 46.22 | E | C |
| ATOM | 6652 | ND1 | HIS | E | 291 | −31.068 | 62.890 | 26.505 | 1.00 | 47.31 | E | N |
| ATOM | 6653 | CE1 | HIS | E | 291 | −31.781 | 62.753 | 25.401 | 1.00 | 48.14 | E | C |
| ATOM | 6654 | NE2 | HIS | E | 291 | −32.601 | 61.729 | 25.560 | 1.00 | 47.40 | E | N |
| ATOM | 6655 | C | HIS | E | 291 | −30.855 | 62.562 | 31.164 | 1.00 | 36.43 | E | C |
| ATOM | 6656 | O | HIS | E | 291 | −31.268 | 61.661 | 31.891 | 1.00 | 38.15 | E | O |
| ATOM | 6657 | N | ARG | E | 292 | −29.882 | 63.381 | 31.537 | 1.00 | 32.78 | E | N |
| ATOM | 6658 | CA | ARG | E | 292 | −29.227 | 63.154 | 32.798 | 1.00 | 28.93 | E | C |
| ATOM | 6659 | CB | ARG | E | 292 | −28.157 | 62.081 | 32.596 | 1.00 | 28.62 | E | C |
| ATOM | 6660 | CG | ARG | E | 292 | −28.519 | 60.733 | 33.155 | 1.00 | 29.29 | E | C |
| ATOM | 6661 | CD | ARG | E | 292 | −27.963 | 59.634 | 32.301 | 1.00 | 28.93 | E | C |
| ATOM | 6662 | NE | ARG | E | 292 | −29.022 | 58.829 | 31.694 | 1.00 | 30.32 | E | N |
| ATOM | 6663 | CZ | ARG | E | 292 | −29.825 | 58.007 | 32.364 | 1.00 | 29.07 | E | C |
| ATOM | 6664 | NH1 | ARG | E | 292 | −29.706 | 57.867 | 33.676 | 1.00 | 31.75 | E | N |
| ATOM | 6665 | NH2 | ARG | E | 292 | −30.746 | 57.312 | 31.719 | 1.00 | 27.34 | E | N |
| ATOM | 6666 | C | ARG | E | 292 | −28.577 | 64.341 | 33.482 | 1.00 | 28.04 | E | C |
| ATOM | 6667 | O | ARG | E | 292 | −28.348 | 65.410 | 32.887 | 1.00 | 27.55 | E | O |
| ATOM | 6668 | N | ASP | E | 293 | −28.297 | 64.107 | 34.762 | 1.00 | 24.80 | E | N |
| ATOM | 6669 | CA | ASP | E | 293 | −27.582 | 65.020 | 35.640 | 1.00 | 22.90 | E | C |
| ATOM | 6670 | CB | ASP | E | 293 | −28.513 | 66.014 | 36.360 | 1.00 | 20.68 | E | C |
| ATOM | 6671 | CG | ASP | E | 293 | −29.551 | 65.346 | 37.235 | 1.00 | 22.20 | E | C |
| ATOM | 6672 | OD1 | ASP | E | 293 | −30.608 | 65.978 | 37.449 | 1.00 | 22.64 | E | O |
| ATOM | 6673 | OD2 | ASP | E | 293 | −29.325 | 64.216 | 37.715 | 1.00 | 20.49 | E | O |
| ATOM | 6674 | C | ASP | E | 293 | −26.897 | 64.055 | 36.602 | 1.00 | 21.61 | E | C |
| ATOM | 6675 | O | ASP | E | 293 | −27.173 | 62.853 | 36.557 | 1.00 | 19.19 | E | O |
| ATOM | 6676 | N | PHE | E | 294 | −25.995 | 64.549 | 37.442 | 1.00 | 21.02 | E | N |
| ATOM | 6677 | CA | PHE | E | 294 | −25.275 | 63.672 | 38.361 | 1.00 | 20.17 | E | C |
| ATOM | 6678 | CB | PHE | E | 294 | −24.459 | 64.505 | 39.354 | 1.00 | 20.82 | E | C |
| ATOM | 6679 | CG | PHE | E | 294 | −23.688 | 63.677 | 40.343 | 1.00 | 20.88 | E | C |
| ATOM | 6680 | CD1 | PHE | E | 294 | −22.503 | 63.048 | 39.970 | 1.00 | 20.06 | E | C |
| ATOM | 6681 | CD2 | PHE | E | 294 | −24.156 | 63.506 | 41.640 | 1.00 | 20.58 | E | C |
| ATOM | 6682 | CE1 | PHE | E | 294 | −21.794 | 62.257 | 40.875 | 1.00 | 19.88 | E | C |
| ATOM | 6683 | CE2 | PHE | E | 294 | −23.454 | 62.716 | 42.551 | 1.00 | 20.39 | E | C |
| ATOM | 6684 | CZ | PHE | E | 294 | −22.272 | 62.091 | 42.166 | 1.00 | 19.10 | E | C |
| ATOM | 6685 | C | PHE | E | 294 | −26.160 | 62.700 | 39.135 | 1.00 | 18.94 | E | C |
| ATOM | 6686 | O | PHE | E | 294 | −25.814 | 61.536 | 39.316 | 1.00 | 18.68 | E | O |
| ATOM | 6687 | N | TYR | E | 295 | −27.314 | 63.176 | 39.568 | 1.00 | 19.05 | E | N |
| ATOM | 6688 | CA | TYR | E | 295 | −28.214 | 62.362 | 40.360 | 1.00 | 19.61 | E | C |
| ATOM | 6689 | CB | TYR | E | 295 | −29.311 | 63.253 | 40.928 | 1.00 | 18.88 | E | C |
| ATOM | 6690 | CG | TYR | E | 295 | −28.707 | 64.269 | 41.854 | 1.00 | 21.65 | E | C |
| ATOM | 6691 | CD1 | TYR | E | 295 | −28.245 | 63.894 | 43.116 | 1.00 | 23.37 | E | C |
| ATOM | 6692 | CE1 | TYR | E | 295 | −27.591 | 64.801 | 43.939 | 1.00 | 24.56 | E | C |
| ATOM | 6693 | CD2 | TYR | E | 295 | −28.503 | 65.580 | 41.442 | 1.00 | 22.15 | E | C |
| ATOM | 6694 | CE2 | TYR | E | 295 | −27.850 | 66.495 | 42.257 | 1.00 | 22.97 | E | C |
| ATOM | 6695 | CZ | TYR | E | 295 | −27.398 | 66.101 | 43.504 | 1.00 | 25.47 | E | C |
| ATOM | 6696 | OH | TYR | E | 295 | −26.771 | 67.013 | 44.326 | 1.00 | 26.39 | E | O |
| ATOM | 6697 | C | TYR | E | 295 | −28.795 | 61.098 | 39.757 | 1.00 | 20.06 | E | C |
| ATOM | 6698 | O | TYR | E | 295 | −29.162 | 60.184 | 40.496 | 1.00 | 21.12 | E | O |
| ATOM | 6699 | N | ASN | E | 296 | −28.900 | 61.012 | 38.437 | 1.00 | 20.19 | E | N |
| ATOM | 6700 | CA | ASN | E | 296 | −29.418 | 59.775 | 37.875 | 1.00 | 19.30 | E | C |
| ATOM | 6701 | CB | ASN | E | 296 | −30.764 | 59.986 | 37.156 | 1.00 | 20.45 | E | C |
| ATOM | 6702 | CG | ASN | E | 296 | −30.674 | 60.879 | 35.941 | 1.00 | 20.58 | E | C |
| ATOM | 6703 | OD1 | ASN | E | 296 | −31.604 | 60.914 | 35.144 | 1.00 | 20.96 | E | O |
| ATOM | 6704 | ND2 | ASN | E | 296 | −29.575 | 61.610 | 35.794 | 1.00 | 22.56 | E | N |
| ATOM | 6705 | C | ASN | E | 296 | −28.407 | 59.047 | 36.996 | 1.00 | 20.74 | E | C |
| ATOM | 6706 | O | ASN | E | 296 | −28.764 | 58.333 | 36.058 | 1.00 | 20.24 | E | O |
| ATOM | 6707 | N | CYS | E | 297 | −27.134 | 59.241 | 37.341 | 1.00 | 20.85 | E | N |
| ATOM | 6708 | CA | CYS | E | 297 | −26.003 | 58.581 | 36.695 | 1.00 | 19.73 | E | C |
| ATOM | 6709 | CB | CYS | E | 297 | −24.771 | 59.493 | 36.671 | 1.00 | 20.19 | E | C |
| ATOM | 6710 | SG | CYS | E | 297 | −24.722 | 60.688 | 35.333 | 1.00 | 26.54 | E | S |
| ATOM | 6711 | C | CYS | E | 297 | −25.726 | 57.435 | 37.667 | 1.00 | 19.42 | E | C |
| ATOM | 6712 | O | CYS | E | 297 | −25.948 | 57.582 | 38.872 | 1.00 | 17.48 | E | O |
| ATOM | 6713 | N | ARG | E | 298 | −25.260 | 56.298 | 37.170 | 1.00 | 19.95 | E | N |
| ATOM | 6714 | CA | ARG | E | 298 | −24.962 | 55.195 | 38.068 | 1.00 | 20.05 | E | C |
| ATOM | 6715 | CB | ARG | E | 298 | −24.911 | 53.872 | 37.308 | 1.00 | 20.72 | E | C |
| ATOM | 6716 | CG | ARG | E | 298 | −26.217 | 53.117 | 37.315 | 1.00 | 21.96 | E | C |
| ATOM | 6717 | CD | ARG | E | 298 | −27.269 | 53.877 | 36.531 | 1.00 | 21.33 | E | C |
| ATOM | 6718 | NE | ARG | E | 298 | −28.498 | 53.105 | 36.384 | 1.00 | 22.81 | E | N |
| ATOM | 6719 | CZ | ARG | E | 298 | −29.499 | 53.454 | 35.584 | 1.00 | 25.11 | E | C |
| ATOM | 6720 | NH1 | ARG | E | 298 | −29.412 | 54.564 | 34.858 | 1.00 | 27.19 | E | N |
| ATOM | 6721 | NH2 | ARG | E | 298 | −30.592 | 52.707 | 35.521 | 1.00 | 24.14 | E | N |
| ATOM | 6722 | C | ARG | E | 298 | −23.614 | 55.454 | 38.728 | 1.00 | 21.70 | E | C |
| ATOM | 6723 | O | ARG | E | 298 | −22.688 | 55.975 | 38.092 | 1.00 | 21.31 | E | O |
| ATOM | 6724 | N | LYS | E | 299 | −23.519 | 55.104 | 40.008 | 1.00 | 21.38 | E | N |
| ATOM | 6725 | CA | LYS | E | 299 | −22.294 | 55.269 | 40.784 | 1.00 | 19.10 | E | C |
| ATOM | 6726 | CB | LYS | E | 299 | −22.481 | 56.359 | 41.837 | 1.00 | 20.95 | E | C |
| ATOM | 6727 | CG | LYS | E | 299 | −22.016 | 57.737 | 41.407 | 1.00 | 21.71 | E | C |
| ATOM | 6728 | CD | LYS | E | 299 | −23.142 | 58.558 | 40.791 | 1.00 | 22.24 | E | C |
| ATOM | 6729 | CE | LYS | E | 299 | −24.367 | 58.595 | 41.675 | 1.00 | 19.98 | E | C |
| ATOM | 6730 | NZ | LYS | E | 299 | −25.455 | 59.363 | 41.036 | 1.00 | 18.37 | E | N |
| ATOM | 6731 | C | LYS | E | 299 | −22.049 | 53.937 | 41.470 | 1.00 | 18.63 | E | C |
| ATOM | 6732 | O | LYS | E | 299 | −22.983 | 53.329 | 41.977 | 1.00 | 17.93 | E | O |
| ATOM | 6733 | N | VAL | E | 300 | −20.807 | 53.471 | 41.482 | 1.00 | 17.10 | E | N |
| ATOM | 6734 | CA | VAL | E | 300 | −20.504 | 52.198 | 42.125 | 1.00 | 15.92 | E | C |
| ATOM | 6735 | CB | VAL | E | 300 | −19.998 | 51.160 | 41.093 | 1.00 | 14.79 | E | C |
| ATOM | 6736 | CG1 | VAL | E | 300 | −19.690 | 49.839 | 41.786 | 1.00 | 13.20 | E | C |
| ATOM | 6737 | CG2 | VAL | E | 300 | −21.040 | 50.960 | 40.007 | 1.00 | 12.84 | E | C |
| ATOM | 6738 | C | VAL | E | 300 | −19.449 | 52.343 | 43.225 | 1.00 | 16.42 | E | C |
| ATOM | 6739 | O | VAL | E | 300 | −18.412 | 52.976 | 43.015 | 1.00 | 16.72 | E | O |
| ATOM | 6740 | N | ASP | E | 301 | −19.734 | 51.776 | 44.399 | 1.00 | 16.30 | E | N |
| ATOM | 6741 | CA | ASP | E | 301 | −18.801 | 51.795 | 45.529 | 1.00 | 14.95 | E | C |
| ATOM | 6742 | CB | ASP | E | 301 | −19.534 | 51.519 | 46.845 | 1.00 | 15.71 | E | C |
| ATOM | 6743 | CG | ASP | E | 301 | −18.775 | 52.042 | 48.064 | 1.00 | 17.29 | E | C |
| ATOM | 6744 | OD1 | ASP | E | 301 | −19.421 | 52.271 | 49.109 | 1.00 | 19.16 | E | O |
| ATOM | 6745 | OD2 | ASP | E | 301 | −17.543 | 52.223 | 47.985 | 1.00 | 14.64 | E | O |
| ATOM | 6746 | C | ASP | E | 301 | −17.880 | 50.644 | 45.199 | 1.00 | 12.81 | E | C |
| ATOM | 6747 | O | ASP | E | 301 | −18.165 | 49.492 | 45.512 | 1.00 | 12.47 | E | O |
| ATOM | 6748 | N | THR | E | 302 | −16.777 | 50.972 | 44.549 | 1.00 | 12.17 | E | N |
| ATOM | 6749 | CA | THR | E | 302 | −15.822 | 49.986 | 44.079 | 1.00 | 13.56 | E | C |
| ATOM | 6750 | CB | THR | E | 302 | −14.950 | 50.614 | 42.980 | 1.00 | 14.22 | E | C |
| ATOM | 6751 | OG1 | THR | E | 302 | −14.572 | 51.938 | 43.384 | 1.00 | 14.79 | E | O |
| ATOM | 6752 | CG2 | THR | E | 302 | −15.735 | 50.704 | 41.659 | 1.00 | 9.75 | E | C |
| ATOM | 6753 | C | THR | E | 302 | −14.913 | 49.391 | 45.142 | 1.00 | 15.83 | E | C |
| ATOM | 6754 | O | THR | E | 302 | −14.155 | 48.458 | 44.872 | 1.00 | 13.35 | E | O |
| ATOM | 6755 | N | HIS | E | 303 | −14.987 | 49.924 | 46.352 | 1.00 | 16.82 | E | N |
| ATOM | 6756 | CA | HIS | E | 303 | −14.139 | 49.429 | 47.425 | 1.00 | 18.42 | E | C |
| ATOM | 6757 | CB | HIS | E | 303 | −12.822 | 50.205 | 47.402 | 1.00 | 19.45 | E | C |
| ATOM | 6758 | CG | HIS | E | 303 | −12.052 | 50.158 | 48.684 | 1.00 | 22.36 | E | C |
| ATOM | 6759 | CD2 | HIS | E | 303 | −11.714 | 49.123 | 49.491 | 1.00 | 21.35 | E | C |
| ATOM | 6760 | ND1 | HIS | E | 303 | −11.489 | 51.283 | 49.246 | 1.00 | 22.51 | E | N |
| ATOM | 6761 | CE1 | HIS | E | 303 | −10.837 | 50.943 | 50.344 | 1.00 | 22.34 | E | C |
| ATOM | 6762 | NE2 | HIS | E | 303 | −10.959 | 49.639 | 50.514 | 1.00 | 19.95 | E | N |
| ATOM | 6763 | C | HIS | E | 303 | −14.868 | 49.597 | 48.747 | 1.00 | 18.49 | E | C |
| ATOM | 6764 | O | HIS | E | 303 | −14.870 | 50.681 | 49.329 | 1.00 | 17.47 | E | O |
| ATOM | 6765 | N | ILE | E | 304 | −15.509 | 48.517 | 49.197 | 1.00 | 18.85 | E | N |
| ATOM | 6766 | CA | ILE | E | 304 | −16.258 | 48.520 | 50.445 | 1.00 | 18.33 | E | C |
| ATOM | 6767 | CB | ILE | E | 304 | −17.730 | 48.973 | 50.217 | 1.00 | 17.38 | E | C |
| ATOM | 6768 | CG2 | ILE | E | 304 | −18.335 | 48.207 | 49.061 | 1.00 | 17.05 | E | C |
| ATOM | 6769 | CG1 | ILE | E | 304 | −18.554 | 48.739 | 51.485 | 1.00 | 18.17 | E | C |
| ATOM | 6770 | CD1 | ILE | E | 304 | −19.743 | 49.652 | 51.618 | 1.00 | 17.20 | E | C |
| ATOM | 6771 | C | ILE | E | 304 | −16.245 | 47.125 | 51.073 | 1.00 | 19.05 | E | C |
| ATOM | 6772 | O | ILE | E | 304 | −16.299 | 46.121 | 50.363 | 1.00 | 18.02 | E | O |
| ATOM | 6773 | N | HIS | E | 305 | −16.168 | 47.078 | 52.405 | 1.00 | 19.13 | E | N |
| ATOM | 6774 | CA | HIS | E | 305 | −16.143 | 45.816 | 53.141 | 1.00 | 16.35 | E | C |
| ATOM | 6775 | CB | HIS | E | 305 | −15.061 | 45.872 | 54.223 | 1.00 | 15.26 | E | C |
| ATOM | 6776 | CG | HIS | E | 305 | −13.705 | 46.264 | 53.708 | 1.00 | 13.86 | E | C |
| ATOM | 6777 | CD2 | HIS | E | 305 | −13.196 | 47.473 | 53.366 | 1.00 | 15.43 | E | C |
| ATOM | 6778 | ND1 | HIS | E | 305 | −12.696 | 45.348 | 53.485 | 1.00 | 13.95 | E | N |
| ATOM | 6779 | CE1 | HIS | E | 305 | −11.624 | 45.977 | 53.035 | 1.00 | 13.42 | E | C |
| ATOM | 6780 | NE2 | HIS | E | 305 | −11.901 | 47.266 | 52.953 | 1.00 | 10.36 | E | N |
| ATOM | 6781 | C | HIS | E | 305 | −17.511 | 45.517 | 53.755 | 1.00 | 15.38 | E | C |
| ATOM | 6782 | O | HIS | E | 305 | −18.098 | 46.363 | 54.426 | 1.00 | 17.02 | E | O |
| ATOM | 6783 | N | ALA | E | 306 | −18.011 | 44.307 | 53.507 | 1.00 | 14.32 | E | N |
| ATOM | 6784 | CA | ALA | E | 306 | −19.318 | 43.869 | 53.997 | 1.00 | 14.91 | E | C |
| ATOM | 6785 | CB | ALA | E | 306 | −19.538 | 42.390 | 53.656 | 1.00 | 11.35 | E | C |
| ATOM | 6786 | C | ALA | E | 306 | −19.518 | 44.094 | 55.496 | 1.00 | 15.76 | E | C |
| ATOM | 6787 | O | ALA | E | 306 | −20.576 | 44.555 | 55.923 | 1.00 | 17.33 | E | O |
| ATOM | 6788 | N | ALA | E | 307 | −18.499 | 43.776 | 56.285 | 1.00 | 16.36 | E | N |
| ATOM | 6789 | CA | ALA | E | 307 | −18.564 | 43.930 | 57.736 | 1.00 | 17.77 | E | C |
| ATOM | 6790 | CB | ALA | E | 307 | −17.273 | 43.436 | 58.361 | 1.00 | 14.60 | E | C |
| ATOM | 6791 | C | ALA | E | 307 | −18.837 | 45.359 | 58.198 | 1.00 | 18.13 | E | C |
| ATOM | 6792 | O | ALA | E | 307 | −19.190 | 45.573 | 59.357 | 1.00 | 21.52 | E | O |
| ATOM | 6793 | N | ALA | E | 308 | −18.685 | 46.332 | 57.304 | 1.00 | 16.99 | E | N |
| ATOM | 6794 | CA | ALA | E | 308 | −18.909 | 47.723 | 57.665 | 1.00 | 16.51 | E | C |
| ATOM | 6795 | CB | ALA | E | 308 | −17.583 | 48.423 | 57.820 | 1.00 | 16.22 | E | C |
| ATOM | 6796 | C | ALA | E | 308 | −19.769 | 48.478 | 56.668 | 1.00 | 17.76 | E | C |
| ATOM | 6797 | O | ALA | E | 308 | −19.788 | 49.708 | 56.675 | 1.00 | 16.53 | E | O |
| ATOM | 6798 | N | CYS | E | 309 | −20.497 | 47.752 | 55.828 | 1.00 | 19.58 | E | N |
| ATOM | 6799 | CA | CYS | E | 309 | −21.333 | 48.385 | 54.812 | 1.00 | 21.15 | E | C |
| ATOM | 6800 | CB | CYS | E | 309 | −21.725 | 47.357 | 53.738 | 1.00 | 21.35 | E | C |
| ATOM | 6801 | SG | CYS | E | 309 | −22.855 | 46.030 | 54.256 | 1.00 | 21.97 | E | S |
| ATOM | 6802 | C | CYS | E | 309 | −22.581 | 49.089 | 55.344 | 1.00 | 22.27 | E | C |
| ATOM | 6803 | O | CYS | E | 309 | −23.254 | 49.814 | 54.604 | 1.00 | 22.71 | E | O |
| ATOM | 6804 | N | MET | E | 310 | −22.892 | 48.889 | 56.620 | 1.00 | 21.83 | E | N |
| ATOM | 6805 | CA | MET | E | 310 | −24.070 | 49.522 | 57.216 | 1.00 | 20.40 | E | C |
| ATOM | 6806 | CB | MET | E | 310 | −24.798 | 48.526 | 58.128 | 1.00 | 19.88 | E | C |
| ATOM | 6807 | CG | MET | E | 310 | −24.093 | 48.273 | 59.467 | 1.00 | 18.45 | E | C |
| ATOM | 6808 | SD | MET | E | 310 | −22.549 | 47.317 | 59.337 | 1.00 | 18.35 | E | S |
| ATOM | 6809 | CE | MET | E | 310 | −23.113 | 45.876 | 58.423 | 1.00 | 17.05 | E | C |
| ATOM | 6810 | C | MET | E | 310 | −23.693 | 50.770 | 58.017 | 1.00 | 20.67 | E | C |
| ATOM | 6811 | O | MET | E | 310 | −22.561 | 50.908 | 58.473 | 1.00 | 16.98 | E | O |
| ATOM | 6812 | N | ASN | E | 311 | −24.644 | 51.687 | 58.171 | 1.00 | 22.48 | E | N |
| ATOM | 6813 | CA | ASN | E | 311 | −24.394 | 52.894 | 58.946 | 1.00 | 25.68 | E | C |
| ATOM | 6814 | CB | ASN | E | 311 | −25.472 | 53.951 | 58.682 | 1.00 | 30.18 | E | C |
| ATOM | 6815 | CG | ASN | E | 311 | −25.231 | 55.238 | 59.468 | 1.00 | 36.79 | E | C |
| ATOM | 6816 | OD1 | ASN | E | 311 | −24.167 | 55.860 | 59.364 | 1.00 | 40.93 | E | O |
| ATOM | 6817 | ND2 | ASN | E | 311 | −26.219 | 55.641 | 60.261 | 1.00 | 38.98 | E | N |
| ATOM | 6818 | C | ASN | E | 311 | −24.418 | 52.501 | 60.422 | 1.00 | 25.17 | E | C |
| ATOM | 6819 | O | ASN | E | 311 | −25.102 | 51.551 | 60.809 | 1.00 | 22.51 | E | O |
| ATOM | 6820 | N | GLN | E | 312 | −23.668 | 53.224 | 61.245 | 1.00 | 24.85 | E | N |
| ATOM | 6821 | CA | GLN | E | 312 | −23.638 | 52.915 | 62.661 | 1.00 | 24.11 | E | C |
| ATOM | 6822 | CB | GLN | E | 312 | −22.659 | 53.841 | 63.376 | 1.00 | 22.49 | E | C |
| ATOM | 6823 | CG | GLN | E | 312 | −22.996 | 55.304 | 63.290 | 1.00 | 20.69 | E | C |
| ATOM | 6824 | CD | GLN | E | 312 | −22.016 | 56.153 | 64.078 | 1.00 | 21.34 | E | C |
| ATOM | 6825 | OE1 | GLN | E | 312 | −21.238 | 55.635 | 64.881 | 1.00 | 20.59 | E | O |
| ATOM | 6826 | NE2 | GLN | E | 312 | −22.043 | 57.463 | 63.848 | 1.00 | 22.04 | E | N |
| ATOM | 6827 | C | GLN | E | 312 | −25.043 | 53.021 | 63.274 | 1.00 | 23.86 | E | C |
| ATOM | 6828 | O | GLN | E | 312 | −25.383 | 52.260 | 64.176 | 1.00 | 24.13 | E | O |
| ATOM | 6829 | N | LYS | E | 313 | −25.860 | 53.948 | 62.773 | 1.00 | 23.06 | E | N |
| ATOM | 6830 | CA | LYS | E | 313 | −27.223 | 54.113 | 63.279 | 1.00 | 22.73 | E | C |
| ATOM | 6831 | CB | LYS | E | 313 | −27.824 | 55.429 | 62.792 | 1.00 | 23.93 | E | C |
| ATOM | 6832 | CG | LYS | E | 313 | −27.528 | 56.611 | 63.709 | 1.00 | 28.70 | E | C |
| ATOM | 6833 | CD | LYS | E | 313 | −28.408 | 57.805 | 63.387 | 1.00 | 33.40 | E | C |
| ATOM | 6834 | CE | LYS | E | 313 | −28.111 | 58.346 | 61.996 | 1.00 | 37.38 | E | C |
| ATOM | 6835 | NZ | LYS | E | 313 | −29.191 | 59.266 | 61.530 | 1.00 | 39.40 | E | N |
| ATOM | 6836 | C | LYS | E | 313 | −28.101 | 52.956 | 62.828 | 1.00 | 22.35 | E | C |
| ATOM | 6837 | O | LYS | E | 313 | −29.096 | 52.620 | 63.479 | 1.00 | 22.30 | E | O |
| ATOM | 6838 | N | HIS | E | 314 | −27.725 | 52.358 | 61.703 | 1.00 | 22.39 | E | N |
| ATOM | 6839 | CA | HIS | E | 314 | −28.438 | 51.219 | 61.143 | 1.00 | 21.46 | E | C |
| ATOM | 6840 | CB | HIS | E | 314 | −27.944 | 50.963 | 59.709 | 1.00 | 23.00 | E | C |
| ATOM | 6841 | CG | HIS | E | 314 | −28.615 | 49.815 | 59.018 | 1.00 | 24.47 | E | C |
| ATOM | 6842 | CD2 | HIS | E | 314 | −28.390 | 49.254 | 57.807 | 1.00 | 24.48 | E | C |
| ATOM | 6843 | ND1 | HIS | E | 314 | −29.649 | 49.097 | 59.585 | 1.00 | 26.28 | E | N |
| ATOM | 6844 | CE1 | HIS | E | 314 | −30.030 | 48.144 | 58.751 | 1.00 | 26.15 | E | C |
| ATOM | 6845 | NE2 | HIS | E | 314 | −29.282 | 48.218 | 57.666 | 1.00 | 25.22 | E | N |
| ATOM | 6846 | C | HIS | E | 314 | −28.142 | 50.018 | 62.047 | 1.00 | 21.20 | E | C |
| ATOM | 6847 | O | HIS | E | 314 | −29.049 | 49.293 | 62.450 | 1.00 | 20.33 | E | O |
| ATOM | 6848 | N | LEU | E | 315 | −26.867 | 49.820 | 62.371 | 1.00 | 19.42 | E | N |
| ATOM | 6849 | CA | LEU | E | 315 | −26.475 | 48.719 | 63.241 | 1.00 | 20.26 | E | C |
| ATOM | 6850 | CB | LEU | E | 315 | −24.953 | 48.664 | 63.378 | 1.00 | 18.95 | E | C |
| ATOM | 6851 | CG | LEU | E | 315 | −24.440 | 47.728 | 64.477 | 1.00 | 18.73 | E | C |
| ATOM | 6852 | CD1 | LEU | E | 315 | −24.804 | 46.290 | 64.130 | 1.00 | 16.44 | E | C |
| ATOM | 6853 | CD2 | LEU | E | 315 | −22.930 | 47.890 | 64.641 | 1.00 | 16.69 | E | C |
| ATOM | 6854 | C | LEU | E | 315 | −27.114 | 48.883 | 64.627 | 1.00 | 21.14 | E | C |
| ATOM | 6855 | O | LEU | E | 315 | −27.630 | 47.921 | 65.201 | 1.00 | 21.30 | E | O |
| ATOM | 6856 | N | LEU | E | 316 | −27.081 | 50.101 | 65.159 | 1.00 | 20.77 | E | N |
| ATOM | 6857 | CA | LEU | E | 316 | −27.660 | 50.372 | 66.469 | 1.00 | 21.60 | E | C |
| ATOM | 6858 | CB | LEU | E | 316 | −27.492 | 51.850 | 66.825 | 1.00 | 20.52 | E | C |
| ATOM | 6859 | CG | LEU | E | 316 | −28.040 | 52.271 | 68.193 | 1.00 | 19.97 | E | C |
| ATOM | 6860 | CD1 | LEU | E | 316 | −27.210 | 51.622 | 69.293 | 1.00 | 19.85 | E | C |
| ATOM | 6861 | CD2 | LEU | E | 316 | −28.007 | 53.778 | 68.323 | 1.00 | 19.28 | E | C |
| ATOM | 6862 | C | LEU | E | 316 | −29.142 | 50.011 | 66.467 | 1.00 | 22.94 | E | C |
| ATOM | 6863 | O | LEU | E | 316 | −29.654 | 49.373 | 67.386 | 1.00 | 24.11 | E | O |
| ATOM | 6864 | N | ARG | E | 317 | −29.827 | 50.431 | 65.416 | 1.00 | 24.18 | E | N |
| ATOM | 6865 | CA | ARG | E | 317 | −31.245 | 50.166 | 65.254 | 1.00 | 24.39 | E | C |
| ATOM | 6866 | CB | ARG | E | 317 | −31.714 | 50.777 | 63.932 | 1.00 | 28.44 | E | C |
| ATOM | 6867 | CG | ARG | E | 317 | −33.212 | 50.874 | 63.757 | 1.00 | 32.01 | E | C |
| ATOM | 6868 | CD | ARG | E | 317 | −33.576 | 52.043 | 62.838 | 1.00 | 35.80 | E | C |
| ATOM | 6869 | NE | ARG | E | 317 | −32.897 | 51.980 | 61.540 | 1.00 | 38.43 | E | N |
| ATOM | 6870 | CZ | ARG | E | 317 | −32.098 | 52.933 | 61.064 | 1.00 | 39.63 | E | C |
| ATOM | 6871 | NH1 | ARG | E | 317 | −31.872 | 54.029 | 61.780 | 1.00 | 40.59 | E | N |
| ATOM | 6872 | NH2 | ARG | E | 317 | −31.529 | 52.799 | 59.871 | 1.00 | 40.43 | E | N |
| ATOM | 6873 | C | ARG | E | 317 | −31.525 | 48.667 | 65.262 | 1.00 | 24.34 | E | C |
| ATOM | 6874 | O | ARG | E | 317 | −32.442 | 48.205 | 65.937 | 1.00 | 25.57 | E | O |
| ATOM | 6875 | N | PHE | E | 318 | −30.729 | 47.908 | 64.512 | 1.00 | 22.52 | E | N |
| ATOM | 6876 | CA | PHE | E | 318 | −30.917 | 46.469 | 64.416 | 1.00 | 21.53 | E | C |
| ATOM | 6877 | CB | PHE | E | 318 | −30.041 | 45.882 | 63.310 | 1.00 | 20.31 | E | C |
| ATOM | 6878 | CG | PHE | E | 318 | −30.220 | 44.400 | 63.125 | 1.00 | 20.76 | E | C |
| ATOM | 6879 | CD1 | PHE | E | 318 | −31.188 | 43.905 | 62.257 | 1.00 | 19.32 | E | C |
| ATOM | 6880 | CD2 | PHE | E | 318 | −29.449 | 43.498 | 63.850 | 1.00 | 19.13 | E | C |
| ATOM | 6881 | CE1 | PHE | E | 318 | −31.387 | 42.532 | 62.117 | 1.00 | 19.27 | E | C |
| ATOM | 6882 | CE2 | PHE | E | 318 | −29.642 | 42.127 | 63.716 | 1.00 | 19.64 | E | C |
| ATOM | 6883 | CZ | PHE | E | 318 | −30.614 | 41.644 | 62.849 | 1.00 | 18.64 | E | C |
| ATOM | 6884 | C | PHE | E | 318 | −30.632 | 45.731 | 65.714 | 1.00 | 21.99 | E | C |
| ATOM | 6885 | O | PHE | E | 318 | −31.279 | 44.724 | 66.025 | 1.00 | 21.87 | E | O |
| ATOM | 6886 | N | ILE | E | 319 | −29.653 | 46.211 | 66.466 | 1.00 | 20.51 | E | N |
| ATOM | 6887 | CA | ILE | E | 319 | −29.326 | 45.555 | 67.718 | 1.00 | 20.61 | E | C |
| ATOM | 6888 | CB | ILE | E | 319 | −28.128 | 46.224 | 68.397 | 1.00 | 18.90 | E | C |
| ATOM | 6889 | CG2 | ILE | E | 319 | −28.036 | 45.786 | 69.854 | 1.00 | 18.99 | E | C |
| ATOM | 6890 | CG1 | ILE | E | 319 | −26.851 | 45.848 | 67.654 | 1.00 | 17.41 | E | C |
| ATOM | 6891 | CD1 | ILE | E | 319 | −25.656 | 46.624 | 68.103 | 1.00 | 17.36 | E | C |
| ATOM | 6892 | C | ILE | E | 319 | −30.535 | 45.607 | 68.644 | 1.00 | 22.02 | E | C |
| ATOM | 6893 | O | ILE | E | 319 | −30.929 | 44.593 | 69.220 | 1.00 | 24.19 | E | O |
| ATOM | 6894 | N | LYS | E | 320 | −31.136 | 46.787 | 68.768 | 1.00 | 22.40 | E | N |
| ATOM | 6895 | CA | LYS | E | 320 | −32.295 | 46.951 | 69.630 | 1.00 | 24.49 | E | C |
| ATOM | 6896 | CB | LYS | E | 320 | −32.695 | 48.419 | 69.680 | 1.00 | 22.13 | E | C |
| ATOM | 6897 | CG | LYS | E | 320 | −31.586 | 49.312 | 70.196 | 1.00 | 21.91 | E | C |
| ATOM | 6898 | CD | LYS | E | 320 | −32.109 | 50.683 | 70.569 | 1.00 | 21.46 | E | C |
| ATOM | 6899 | CE | LYS | E | 320 | −31.051 | 51.486 | 71.301 | 1.00 | 24.14 | E | C |
| ATOM | 6900 | NZ | LYS | E | 320 | −31.306 | 52.946 | 71.182 | 1.00 | 25.97 | E | N |
| ATOM | 6901 | C | LYS | E | 320 | −33.476 | 46.093 | 69.181 | 1.00 | 27.01 | E | C |
| ATOM | 6902 | O | LYS | E | 320 | −34.166 | 45.492 | 70.007 | 1.00 | 28.38 | E | O |
| ATOM | 6903 | N | LYS | E | 321 | −33.702 | 46.025 | 67.875 | 1.00 | 27.88 | E | N |
| ATOM | 6904 | CA | LYS | E | 321 | −34.800 | 45.229 | 67.337 | 1.00 | 29.54 | E | C |
| ATOM | 6905 | CB | LYS | E | 321 | −34.939 | 45.467 | 65.829 | 1.00 | 30.65 | E | C |
| ATOM | 6906 | CG | LYS | E | 321 | −36.259 | 44.993 | 65.247 | 1.00 | 34.11 | E | C |
| ATOM | 6907 | CD | LYS | E | 321 | −37.441 | 45.703 | 65.901 | 1.00 | 38.23 | E | C |
| ATOM | 6908 | CE | LYS | E | 321 | −38.780 | 45.224 | 65.340 | 1.00 | 39.86 | E | C |
| ATOM | 6909 | NZ | LYS | E | 321 | −38.724 | 43.813 | 64.859 | 1.00 | 42.69 | E | N |
| ATOM | 6910 | C | LYS | E | 321 | −34.584 | 43.746 | 67.602 | 1.00 | 28.35 | E | C |
| ATOM | 6911 | O | LYS | E | 321 | −35.525 | 43.021 | 67.908 | 1.00 | 28.97 | E | O |
| ATOM | 6912 | N | SER | E | 322 | −33.341 | 43.296 | 67.481 | 1.00 | 28.09 | E | N |
| ATOM | 6913 | CA | SER | E | 322 | −33.021 | 41.894 | 67.711 | 1.00 | 28.95 | E | C |
| ATOM | 6914 | CB | SER | E | 322 | −31.544 | 41.632 | 67.402 | 1.00 | 27.52 | E | C |
| ATOM | 6915 | OG | SER | E | 322 | −30.704 | 42.202 | 68.389 | 1.00 | 28.01 | E | O |
| ATOM | 6916 | C | SER | E | 322 | −33.331 | 41.488 | 69.149 | 1.00 | 30.08 | E | C |
| ATOM | 6917 | O | SER | E | 322 | −33.706 | 40.346 | 69.414 | 1.00 | 29.49 | E | O |
| ATOM | 6918 | N | TYR | E | 323 | −33.174 | 42.427 | 70.076 | 1.00 | 30.70 | E | N |
| ATOM | 6919 | CA | TYR | E | 323 | −33.441 | 42.153 | 71.479 | 1.00 | 33.46 | E | C |
| ATOM | 6920 | CB | TYR | E | 323 | −32.806 | 43.228 | 72.360 | 1.00 | 34.72 | E | C |
| ATOM | 6921 | CG | TYR | E | 323 | −33.067 | 43.030 | 73.834 | 1.00 | 35.80 | E | C |
| ATOM | 6922 | CD1 | TYR | E | 323 | −34.142 | 43.657 | 74.458 | 1.00 | 37.19 | E | C |
| ATOM | 6923 | CE1 | TYR | E | 323 | −34.391 | 43.477 | 75.810 | 1.00 | 39.16 | E | C |
| ATOM | 6924 | CD2 | TYR | E | 323 | −32.241 | 42.214 | 74.604 | 1.00 | 36.95 | E | C |
| ATOM | 6925 | CE2 | TYR | E | 323 | −32.479 | 42.027 | 75.958 | 1.00 | 38.82 | E | C |
| ATOM | 6926 | CZ | TYR | E | 323 | −33.556 | 42.662 | 76.556 | 1.00 | 39.95 | E | C |
| ATOM | 6927 | OH | TYR | E | 323 | −33.800 | 42.487 | 77.902 | 1.00 | 43.16 | E | O |
| ATOM | 6928 | C | TYR | E | 323 | −34.940 | 42.099 | 71.743 | 1.00 | 33.95 | E | C |
| ATOM | 6929 | O | TYR | E | 323 | −35.424 | 41.247 | 72.489 | 1.00 | 35.15 | E | O |
| ATOM | 6930 | N | GLN | E | 324 | −35.673 | 43.014 | 71.125 | 1.00 | 33.87 | E | N |
| ATOM | 6931 | CA | GLN | E | 324 | −37.111 | 43.067 | 71.295 | 1.00 | 34.97 | E | C |
| ATOM | 6932 | CB | GLN | E | 324 | −37.686 | 44.243 | 70.499 | 1.00 | 37.89 | E | C |
| ATOM | 6933 | CG | GLN | E | 324 | −39.192 | 44.178 | 70.271 | 1.00 | 43.00 | E | C |
| ATOM | 6934 | CD | GLN | E | 324 | −39.630 | 44.946 | 69.032 | 1.00 | 47.13 | E | C |
| ATOM | 6935 | OE1 | GLN | E | 324 | −39.172 | 46.069 | 68.782 | 1.00 | 48.15 | E | O |
| ATOM | 6936 | NE2 | GLN | E | 324 | −40.521 | 44.342 | 68.247 | 1.00 | 47.61 | E | N |
| ATOM | 6937 | C | GLN | E | 324 | −37.766 | 41.767 | 70.844 | 1.00 | 33.84 | E | C |
| ATOM | 6938 | O | GLN | E | 324 | −38.765 | 41.343 | 71.418 | 1.00 | 34.75 | E | O |
| ATOM | 6939 | N | VAL | E | 325 | −37.199 | 41.123 | 69.829 | 1.00 | 32.97 | E | N |
| ATOM | 6940 | CA | VAL | E | 325 | −37.789 | 39.894 | 69.319 | 1.00 | 31.90 | E | C |
| ATOM | 6941 | CB | VAL | E | 325 | −38.017 | 39.975 | 67.777 | 1.00 | 31.62 | E | C |
| ATOM | 6942 | CG1 | VAL | E | 325 | −38.382 | 41.391 | 67.370 | 1.00 | 28.69 | E | C |
| ATOM | 6943 | CG2 | VAL | E | 325 | −36.785 | 39.500 | 67.041 | 1.00 | 30.34 | E | C |
| ATOM | 6944 | C | VAL | E | 325 | −37.048 | 38.593 | 69.625 | 1.00 | 32.17 | E | C |
| ATOM | 6945 | O | VAL | E | 325 | −37.647 | 37.517 | 69.567 | 1.00 | 32.71 | E | O |
| ATOM | 6946 | N | ASP | E | 326 | −35.763 | 38.674 | 69.956 | 1.00 | 31.33 | E | N |
| ATOM | 6947 | CA | ASP | E | 326 | −34.995 | 37.460 | 70.235 | 1.00 | 31.04 | E | C |
| ATOM | 6948 | CB | ASP | E | 326 | −33.920 | 37.258 | 69.164 | 1.00 | 31.58 | E | C |
| ATOM | 6949 | CG | ASP | E | 326 | −34.482 | 36.733 | 67.856 | 1.00 | 33.65 | E | C |
| ATOM | 6950 | OD1 | ASP | E | 326 | −35.639 | 36.254 | 67.849 | 1.00 | 35.37 | E | O |
| ATOM | 6951 | OD2 | ASP | E | 326 | −33.763 | 36.800 | 66.831 | 1.00 | 34.13 | E | O |
| ATOM | 6952 | C | ASP | E | 326 | −34.323 | 37.449 | 71.601 | 1.00 | 31.16 | E | C |
| ATOM | 6953 | O | ASP | E | 326 | −33.345 | 36.726 | 71.799 | 1.00 | 28.96 | E | O |
| ATOM | 6954 | N | ALA | E | 327 | −34.840 | 38.242 | 72.537 | 1.00 | 31.63 | E | N |
| ATOM | 6955 | CA | ALA | E | 327 | −34.265 | 38.319 | 73.884 | 1.00 | 32.11 | E | C |
| ATOM | 6956 | CB | ALA | E | 327 | −35.155 | 39.177 | 74.782 | 1.00 | 30.16 | E | C |
| ATOM | 6957 | C | ALA | E | 327 | −34.024 | 36.955 | 74.543 | 1.00 | 32.51 | E | C |
| ATOM | 6958 | O | ALA | E | 327 | −33.063 | 36.782 | 75.294 | 1.00 | 31.82 | E | O |
| ATOM | 6959 | N | ASP | E | 328 | −34.889 | 35.986 | 74.255 | 1.00 | 33.26 | E | N |
| ATOM | 6960 | CA | ASP | E | 328 | −34.758 | 34.662 | 74.851 | 1.00 | 34.50 | E | C |
| ATOM | 6961 | CB | ASP | E | 328 | −36.098 | 34.226 | 75.453 | 1.00 | 35.29 | E | C |
| ATOM | 6962 | CG | ASP | E | 328 | −36.633 | 35.224 | 76.469 | 1.00 | 37.28 | E | C |
| ATOM | 6963 | OD1 | ASP | E | 328 | −35.904 | 35.554 | 77.435 | 1.00 | 36.86 | E | O |
| ATOM | 6964 | OD2 | ASP | E | 328 | −37.784 | 35.680 | 76.297 | 1.00 | 38.42 | E | O |
| ATOM | 6965 | C | ASP | E | 328 | −34.254 | 33.588 | 73.896 | 1.00 | 34.04 | E | C |
| ATOM | 6966 | O | ASP | E | 328 | −34.306 | 32.401 | 74.215 | 1.00 | 34.88 | E | O |
| ATOM | 6967 | N | ARG | E | 329 | −33.765 | 34.002 | 72.731 | 1.00 | 32.61 | E | N |
| ATOM | 6968 | CA | ARG | E | 329 | −33.242 | 33.063 | 71.745 | 1.00 | 30.85 | E | C |
| ATOM | 6969 | CB | ARG | E | 329 | −33.212 | 33.715 | 70.357 | 1.00 | 32.54 | E | C |
| ATOM | 6970 | CG | ARG | E | 329 | −33.333 | 32.740 | 69.188 | 1.00 | 34.10 | E | C |
| ATOM | 6971 | CD | ARG | E | 329 | −32.149 | 32.833 | 68.223 | 1.00 | 34.52 | E | C |
| ATOM | 6972 | NE | ARG | E | 329 | −32.453 | 33.668 | 67.060 | 1.00 | 36.95 | E | N |
| ATOM | 6973 | CZ | ARG | E | 329 | −32.084 | 33.400 | 65.807 | 1.00 | 36.68 | E | C |
| ATOM | 6974 | NH1 | ARG | E | 329 | −31.388 | 32.309 | 65.517 | 1.00 | 36.30 | E | N |
| ATOM | 6975 | NH2 | ARG | E | 329 | −32.406 | 34.238 | 64.836 | 1.00 | 35.83 | E | N |
| ATOM | 6976 | C | ARG | E | 329 | −31.822 | 32.687 | 72.151 | 1.00 | 30.21 | E | C |
| ATOM | 6977 | O | ARG | E | 329 | −31.028 | 33.563 | 72.501 | 1.00 | 28.42 | E | O |
| ATOM | 6978 | N | VAL | E | 330 | −31.501 | 31.394 | 72.127 | 1.00 | 30.17 | E | N |
| ATOM | 6979 | CA | VAL | E | 330 | −30.150 | 30.979 | 72.474 | 1.00 | 30.68 | E | C |
| ATOM | 6980 | CB | VAL | E | 330 | −30.037 | 29.464 | 72.652 | 1.00 | 30.34 | E | C |
| ATOM | 6981 | CG1 | VAL | E | 330 | −28.589 | 29.087 | 72.952 | 1.00 | 28.59 | E | C |
| ATOM | 6982 | CG2 | VAL | E | 330 | −30.944 | 29.014 | 73.784 | 1.00 | 31.06 | E | C |
| ATOM | 6983 | C | VAL | E | 330 | −29.305 | 31.418 | 71.293 | 1.00 | 32.69 | E | C |
| ATOM | 6984 | O | VAL | E | 330 | −29.493 | 30.946 | 70.171 | 1.00 | 32.53 | E | O |
| ATOM | 6985 | N | VAL | E | 331 | −28.367 | 32.319 | 71.549 | 1.00 | 34.29 | E | N |
| ATOM | 6986 | CA | VAL | E | 331 | −27.550 | 32.867 | 70.483 | 1.00 | 35.22 | E | C |
| ATOM | 6987 | CB | VAL | E | 331 | −27.950 | 34.341 | 70.279 | 1.00 | 35.08 | E | C |
| ATOM | 6988 | CG1 | VAL | E | 331 | −27.149 | 35.242 | 71.206 | 1.00 | 32.75 | E | C |
| ATOM | 6989 | CG2 | VAL | E | 331 | −27.776 | 34.725 | 68.846 | 1.00 | 36.35 | E | C |
| ATOM | 6990 | C | VAL | E | 331 | −26.040 | 32.759 | 70.685 | 1.00 | 37.71 | E | C |
| ATOM | 6991 | O | VAL | E | 331 | −25.264 | 32.916 | 69.742 | 1.00 | 36.80 | E | O |
| ATOM | 6992 | N | TYR | E | 332 | −25.629 | 32.469 | 71.912 | 1.00 | 40.75 | E | N |
| ATOM | 6993 | CA | TYR | E | 332 | −24.212 | 32.371 | 72.246 | 1.00 | 42.68 | E | C |
| ATOM | 6994 | CB | TYR | E | 332 | −23.842 | 33.565 | 73.128 | 1.00 | 43.04 | E | C |
| ATOM | 6995 | CG | TYR | E | 332 | −22.403 | 33.649 | 73.581 | 1.00 | 43.44 | E | C |
| ATOM | 6996 | CD1 | TYR | E | 332 | −21.435 | 34.259 | 72.783 | 1.00 | 43.01 | E | C |
| ATOM | 6997 | CE1 | TYR | E | 332 | −20.126 | 34.434 | 73.239 | 1.00 | 43.66 | E | C |
| ATOM | 6998 | CD2 | TYR | E | 332 | −22.027 | 33.203 | 74.852 | 1.00 | 44.97 | E | C |
| ATOM | 6999 | CE2 | TYR | E | 332 | −20.720 | 33.372 | 75.322 | 1.00 | 45.05 | E | C |
| ATOM | 7000 | CZ | TYR | E | 332 | −19.777 | 33.991 | 74.512 | 1.00 | 45.54 | E | C |
| ATOM | 7001 | OH | TYR | E | 332 | −18.498 | 34.187 | 74.985 | 1.00 | 46.05 | E | O |
| ATOM | 7002 | C | TYR | E | 332 | −23.948 | 31.061 | 72.972 | 1.00 | 45.22 | E | C |
| ATOM | 7003 | O | TYR | E | 332 | −24.857 | 30.480 | 73.568 | 1.00 | 45.14 | E | O |
| ATOM | 7004 | N | SER | E | 333 | −22.705 | 30.593 | 72.921 | 1.00 | 47.82 | E | N |
| ATOM | 7005 | CA | SER | E | 333 | −22.358 | 29.343 | 73.581 | 1.00 | 51.69 | E | C |
| ATOM | 7006 | CB | SER | E | 333 | −21.900 | 28.316 | 72.542 | 1.00 | 49.44 | E | C |
| ATOM | 7007 | OG | SER | E | 333 | −21.489 | 27.112 | 73.169 | 1.00 | 49.78 | E | O |
| ATOM | 7008 | C | SER | E | 333 | −21.286 | 29.480 | 74.668 | 1.00 | 55.46 | E | C |
| ATOM | 7009 | O | SER | E | 333 | −20.210 | 30.044 | 74.436 | 1.00 | 55.91 | E | O |
| ATOM | 7010 | N | THR | E | 334 | −21.604 | 28.965 | 75.858 | 1.00 | 58.80 | E | N |
| ATOM | 7011 | CA | THR | E | 334 | −20.686 | 28.972 | 76.999 | 1.00 | 60.43 | E | C |
| ATOM | 7012 | CB | THR | E | 334 | −21.070 | 30.052 | 78.056 | 1.00 | 60.66 | E | C |
| ATOM | 7013 | OG1 | THR | E | 334 | −20.039 | 31.048 | 78.112 | 1.00 | 60.32 | E | O |
| ATOM | 7014 | CG2 | THR | E | 334 | −21.236 | 29.428 | 79.451 | 1.00 | 60.47 | E | C |
| ATOM | 7015 | C | THR | E | 334 | −20.762 | 27.578 | 77.619 | 1.00 | 61.66 | E | C |
| ATOM | 7016 | O | THR | E | 334 | −21.826 | 26.951 | 77.613 | 1.00 | 60.95 | E | O |
| ATOM | 7017 | N | LYS | E | 335 | −19.635 | 27.104 | 78.148 | 1.00 | 62.49 | E | N |
| ATOM | 7018 | CA | LYS | E | 335 | −19.552 | 25.772 | 78.742 | 1.00 | 63.25 | E | C |
| ATOM | 7019 | CB | LYS | E | 335 | −18.294 | 25.650 | 79.604 | 1.00 | 62.07 | E | C |
| ATOM | 7020 | CG | LYS | E | 335 | −17.639 | 24.269 | 79.532 | 1.00 | 62.22 | E | C |
| ATOM | 7021 | CD | LYS | E | 335 | −18.578 | 23.150 | 79.998 | 1.00 | 61.33 | E | C |
| ATOM | 7022 | CE | LYS | E | 335 | −18.672 | 22.025 | 78.967 | 1.00 | 61.29 | E | C |
| ATOM | 7023 | NZ | LYS | E | 335 | −18.553 | 20.667 | 79.585 | 1.00 | 60.82 | E | N |
| ATOM | 7024 | C | LYS | E | 335 | −20.757 | 25.314 | 79.561 | 1.00 | 63.82 | E | C |
| ATOM | 7025 | O | LYS | E | 335 | −21.580 | 24.527 | 79.083 | 1.00 | 64.52 | E | O |
| ATOM | 7026 | N | GLU | E | 336 | −20.852 | 25.790 | 80.799 | 1.00 | 64.65 | E | N |
| ATOM | 7027 | CA | GLU | E | 336 | −21.949 | 25.389 | 81.676 | 1.00 | 65.48 | E | C |
| ATOM | 7028 | CB | GLU | E | 336 | −21.779 | 26.020 | 83.065 | 1.00 | 66.97 | E | C |
| ATOM | 7029 | CG | GLU | E | 336 | −21.735 | 25.008 | 84.219 | 1.00 | 68.62 | E | C |
| ATOM | 7030 | CD | GLU | E | 336 | −21.830 | 23.558 | 83.753 | 1.00 | 70.00 | E | C |
| ATOM | 7031 | OE1 | GLU | E | 336 | −22.965 | 23.066 | 83.554 | 1.00 | 70.67 | E | O |
| ATOM | 7032 | OE2 | GLU | E | 336 | −20.768 | 22.913 | 83.588 | 1.00 | 70.24 | E | O |
| ATOM | 7033 | C | GLU | E | 336 | −23.326 | 25.729 | 81.115 | 1.00 | 64.21 | E | C |
| ATOM | 7034 | O | GLU | E | 336 | −24.331 | 25.137 | 81.524 | 1.00 | 64.55 | E | O |
| ATOM | 7035 | N | LYS | E | 337 | −23.375 | 26.672 | 80.177 | 1.00 | 62.76 | E | N |
| ATOM | 7036 | CA | LYS | E | 337 | −24.646 | 27.062 | 79.580 | 1.00 | 59.78 | E | C |
| ATOM | 7037 | CB | LYS | E | 337 | −25.544 | 27.695 | 80.654 | 1.00 | 60.45 | E | C |
| ATOM | 7038 | CG | LYS | E | 337 | −26.872 | 28.231 | 80.142 | 1.00 | 59.74 | E | C |
| ATOM | 7039 | CD | LYS | E | 337 | −27.561 | 29.092 | 81.195 | 1.00 | 60.65 | E | C |
| ATOM | 7040 | CE | LYS | E | 337 | −28.787 | 29.806 | 80.615 | 1.00 | 61.10 | E | C |
| ATOM | 7041 | NZ | LYS | E | 337 | −30.079 | 29.425 | 81.267 | 1.00 | 60.48 | E | N |
| ATOM | 7042 | C | LYS | E | 337 | −24.491 | 28.028 | 78.404 | 1.00 | 58.38 | E | C |
| ATOM | 7043 | O | LYS | E | 337 | −23.730 | 28.992 | 78.475 | 1.00 | 58.62 | E | O |
| ATOM | 7044 | N | ASN | E | 338 | −25.202 | 27.750 | 77.315 | 1.00 | 54.87 | E | N |
| ATOM | 7045 | CA | ASN | E | 338 | −25.183 | 28.625 | 76.153 | 1.00 | 50.53 | E | C |
| ATOM | 7046 | CB | ASN | E | 338 | −25.738 | 27.899 | 74.928 | 1.00 | 52.17 | E | C |
| ATOM | 7047 | CG | ASN | E | 338 | −25.156 | 26.508 | 74.761 | 1.00 | 53.01 | E | C |
| ATOM | 7048 | OD1 | ASN | E | 338 | −23.939 | 26.339 | 74.649 | 1.00 | 54.24 | E | O |
| ATOM | 7049 | ND2 | ASN | E | 338 | −26.027 | 25.501 | 74.742 | 1.00 | 54.13 | E | N |
| ATOM | 7050 | C | ASN | E | 338 | −26.131 | 29.738 | 76.579 | 1.00 | 47.71 | E | C |
| ATOM | 7051 | O | ASN | E | 338 | −27.124 | 29.470 | 77.247 | 1.00 | 48.30 | E | O |
| ATOM | 7052 | N | LEU | E | 339 | −25.842 | 30.979 | 76.208 | 1.00 | 43.03 | E | N |
| ATOM | 7053 | CA | LEU | E | 339 | −26.694 | 32.088 | 76.624 | 1.00 | 39.70 | E | C |
| ATOM | 7054 | CB | LEU | E | 339 | −25.831 | 33.274 | 77.058 | 1.00 | 40.17 | E | C |
| ATOM | 7055 | CG | LEU | E | 339 | −24.366 | 32.980 | 77.374 | 1.00 | 39.35 | E | C |
| ATOM | 7056 | CD1 | LEU | E | 339 | −23.619 | 34.287 | 77.565 | 1.00 | 40.22 | E | C |
| ATOM | 7057 | CD2 | LEU | E | 339 | −24.274 | 32.123 | 78.628 | 1.00 | 39.99 | E | C |
| ATOM | 7058 | C | LEU | E | 339 | −27.695 | 32.583 | 75.604 | 1.00 | 36.38 | E | C |
| ATOM | 7059 | O | LEU | E | 339 | −27.473 | 32.481 | 74.402 | 1.00 | 35.28 | E | O |
| ATOM | 7060 | N | THR | E | 340 | −28.807 | 33.118 | 76.101 | 1.00 | 33.97 | E | N |
| ATOM | 7061 | CA | THR | E | 340 | −29.818 | 33.689 | 75.232 | 1.00 | 32.76 | E | C |
| ATOM | 7062 | CB | THR | E | 340 | −31.189 | 33.805 | 75.923 | 1.00 | 31.73 | E | C |
| ATOM | 7063 | OG1 | THR | E | 340 | −31.090 | 34.704 | 77.029 | 1.00 | 31.23 | E | O |
| ATOM | 7064 | CG2 | THR | E | 340 | −31.663 | 32.451 | 76.403 | 1.00 | 31.51 | E | C |
| ATOM | 7065 | C | THR | E | 340 | −29.296 | 35.095 | 74.956 | 1.00 | 32.75 | E | C |
| ATOM | 7066 | O | THR | E | 340 | −28.319 | 35.524 | 75.576 | 1.00 | 33.31 | E | O |
| ATOM | 7067 | N | LEU | E | 341 | −29.924 | 35.806 | 74.028 | 1.00 | 31.93 | E | N |
| ATOM | 7068 | CA | LEU | E | 341 | −29.492 | 37.161 | 73.713 | 1.00 | 30.75 | E | C |
| ATOM | 7069 | CB | LEU | E | 341 | −30.441 | 37.797 | 72.685 | 1.00 | 29.70 | E | C |
| ATOM | 7070 | CG | LEU | E | 341 | −30.096 | 39.201 | 72.165 | 1.00 | 28.41 | E | C |
| ATOM | 7071 | CD1 | LEU | E | 341 | −28.692 | 39.207 | 71.594 | 1.00 | 29.35 | E | C |
| ATOM | 7072 | CD2 | LEU | E | 341 | −31.093 | 39.623 | 71.104 | 1.00 | 27.11 | E | C |
| ATOM | 7073 | C | LEU | E | 341 | −29.473 | 37.994 | 74.996 | 1.00 | 31.31 | E | C |
| ATOM | 7074 | O | LEU | E | 341 | −28.494 | 38.687 | 75.289 | 1.00 | 29.95 | E | O |
| ATOM | 7075 | N | LYS | E | 342 | −30.563 | 37.912 | 75.758 | 1.00 | 31.47 | E | N |
| ATOM | 7076 | CA | LYS | E | 342 | −30.698 | 38.648 | 77.009 | 1.00 | 31.04 | E | C |
| ATOM | 7077 | CB | LYS | E | 342 | −32.029 | 38.297 | 77.678 | 1.00 | 32.77 | E | C |
| ATOM | 7078 | CG | LYS | E | 342 | −32.351 | 39.139 | 78.899 | 1.00 | 35.42 | E | C |
| ATOM | 7079 | CD | LYS | E | 342 | −33.728 | 38.797 | 79.451 | 1.00 | 38.72 | E | C |
| ATOM | 7080 | CE | LYS | E | 342 | −34.568 | 40.048 | 79.703 | 1.00 | 40.80 | E | C |
| ATOM | 7081 | NZ | LYS | E | 342 | −35.782 | 40.108 | 78.831 | 1.00 | 42.61 | E | N |
| ATOM | 7082 | C | LYS | E | 342 | −29.551 | 38.340 | 77.966 | 1.00 | 31.01 | E | C |
| ATOM | 7083 | O | LYS | E | 342 | −28.967 | 39.247 | 78.553 | 1.00 | 31.24 | E | O |
| ATOM | 7084 | N | GLN | E | 343 | −29.231 | 37.059 | 78.115 | 1.00 | 29.72 | E | N |
| ATOM | 7085 | CA | GLN | E | 343 | −28.162 | 36.638 | 79.009 | 1.00 | 31.23 | E | C |
| ATOM | 7086 | CB | GLN | E | 343 | −28.097 | 35.116 | 79.090 | 1.00 | 32.87 | E | C |
| ATOM | 7087 | CG | GLN | E | 343 | −29.250 | 34.479 | 79.826 | 1.00 | 35.76 | E | C |
| ATOM | 7088 | CD | GLN | E | 343 | −29.264 | 32.976 | 79.661 | 1.00 | 36.76 | E | C |
| ATOM | 7089 | OE1 | GLN | E | 343 | −28.243 | 32.370 | 79.357 | 1.00 | 36.75 | E | O |
| ATOM | 7090 | NE2 | GLN | E | 343 | −30.426 | 32.367 | 79.856 | 1.00 | 39.29 | E | N |
| ATOM | 7091 | C | GLN | E | 343 | −26.808 | 37.153 | 78.572 | 1.00 | 31.32 | E | C |
| ATOM | 7092 | O | GLN | E | 343 | −25.966 | 37.491 | 79.405 | 1.00 | 31.88 | E | O |
| ATOM | 7093 | N | LEU | E | 344 | −26.582 | 37.188 | 77.264 | 1.00 | 30.72 | E | N |
| ATOM | 7094 | CA | LEU | E | 344 | −25.309 | 37.670 | 76.740 | 1.00 | 30.29 | E | C |
| ATOM | 7095 | CB | LEU | E | 344 | −25.240 | 37.478 | 75.220 | 1.00 | 28.74 | E | C |
| ATOM | 7096 | CG | LEU | E | 344 | −24.002 | 38.064 | 74.534 | 1.00 | 27.20 | E | C |
| ATOM | 7097 | CD1 | LEU | E | 344 | −22.743 | 37.431 | 75.093 | 1.00 | 26.36 | E | C |
| ATOM | 7098 | CD2 | LEU | E | 344 | −24.095 | 37.828 | 73.039 | 1.00 | 27.87 | E | C |
| ATOM | 7099 | C | LEU | E | 344 | −25.127 | 39.144 | 77.090 | 1.00 | 29.97 | E | C |
| ATOM | 7100 | O | LEU | E | 344 | −24.044 | 39.560 | 77.499 | 1.00 | 29.68 | E | O |
| ATOM | 7101 | N | PHE | E | 345 | −26.186 | 39.933 | 76.933 | 1.00 | 29.51 | E | N |
| ATOM | 7102 | CA | PHE | E | 345 | −26.107 | 41.349 | 77.259 | 1.00 | 30.89 | E | C |
| ATOM | 7103 | CB | PHE | E | 345 | −27.372 | 42.075 | 76.795 | 1.00 | 30.24 | E | C |
| ATOM | 7104 | CG | PHE | E | 345 | −27.344 | 42.452 | 75.337 | 1.00 | 32.40 | E | C |
| ATOM | 7105 | CD1 | PHE | E | 345 | −26.405 | 43.363 | 74.859 | 1.00 | 31.76 | E | C |
| ATOM | 7106 | CD2 | PHE | E | 345 | −28.232 | 41.872 | 74.433 | 1.00 | 31.62 | E | C |
| ATOM | 7107 | CE1 | PHE | E | 345 | −26.350 | 43.690 | 73.501 | 1.00 | 29.85 | E | C |
| ATOM | 7108 | CE2 | PHE | E | 345 | −28.179 | 42.194 | 73.077 | 1.00 | 29.28 | E | C |
| ATOM | 7109 | CZ | PHE | E | 345 | −27.238 | 43.103 | 72.612 | 1.00 | 26.75 | E | C |
| ATOM | 7110 | C | PHE | E | 345 | −25.907 | 41.522 | 78.763 | 1.00 | 32.90 | E | C |
| ATOM | 7111 | O | PHE | E | 345 | −25.349 | 42.530 | 79.216 | 1.00 | 32.58 | E | O |
| ATOM | 7112 | N | ASP | E | 346 | −26.362 | 40.529 | 79.528 | 1.00 | 34.64 | E | N |
| ATOM | 7113 | CA | ASP | E | 346 | −26.218 | 40.540 | 80.982 | 1.00 | 35.56 | E | C |
| ATOM | 7114 | CB | ASP | E | 346 | −27.063 | 39.434 | 81.611 | 1.00 | 38.22 | E | C |
| ATOM | 7115 | CG | ASP | E | 346 | −28.440 | 39.911 | 82.005 | 1.00 | 41.23 | E | C |
| ATOM | 7116 | OD1 | ASP | E | 346 | −28.734 | 41.109 | 81.806 | 1.00 | 43.63 | E | O |
| ATOM | 7117 | OD2 | ASP | E | 346 | −29.231 | 39.087 | 82.512 | 1.00 | 43.98 | E | O |
| ATOM | 7118 | C | ASP | E | 346 | −24.755 | 40.307 | 81.322 | 1.00 | 34.46 | E | C |
| ATOM | 7119 | O | ASP | E | 346 | −24.179 | 41.005 | 82.150 | 1.00 | 33.16 | E | O |
| ATOM | 7120 | N | LYS | E | 347 | −24.166 | 39.313 | 80.670 | 1.00 | 33.43 | E | N |
| ATOM | 7121 | CA | LYS | E | 347 | −22.768 | 38.981 | 80.876 | 1.00 | 33.89 | E | C |
| ATOM | 7122 | CB | LYS | E | 347 | −22.388 | 37.767 | 80.026 | 1.00 | 35.82 | E | C |
| ATOM | 7123 | CG | LYS | E | 347 | −20.985 | 37.241 | 80.271 | 1.00 | 39.65 | E | C |
| ATOM | 7124 | CD | LYS | E | 347 | −20.134 | 37.321 | 79.014 | 1.00 | 42.17 | E | C |
| ATOM | 7125 | CE | LYS | E | 347 | −20.083 | 35.985 | 78.295 | 1.00 | 43.49 | E | C |
| ATOM | 7126 | NZ | LYS | E | 347 | −18.758 | 35.328 | 78.440 | 1.00 | 46.20 | E | N |
| ATOM | 7127 | C | LYS | E | 347 | −21.925 | 40.175 | 80.463 | 1.00 | 35.43 | E | C |
| ATOM | 7128 | O | LYS | E | 347 | −20.821 | 40.374 | 80.964 | 1.00 | 36.21 | E | O |
| ATOM | 7129 | N | LEU | E | 348 | −22.455 | 40.977 | 79.546 | 1.00 | 35.74 | E | N |
| ATOM | 7130 | CA | LEU | E | 348 | −21.744 | 42.152 | 79.058 | 1.00 | 35.12 | E | C |
| ATOM | 7131 | CB | LEU | E | 348 | −22.106 | 42.422 | 77.596 | 1.00 | 34.19 | E | C |
| ATOM | 7132 | CG | LEU | E | 348 | −21.610 | 41.386 | 76.582 | 1.00 | 33.36 | E | C |
| ATOM | 7133 | CD1 | LEU | E | 348 | −22.104 | 41.760 | 75.196 | 1.00 | 33.00 | E | C |
| ATOM | 7134 | CD2 | LEU | E | 348 | −20.091 | 41.314 | 76.609 | 1.00 | 29.87 | E | C |
| ATOM | 7135 | C | LEU | E | 348 | −22.065 | 43.377 | 79.896 | 1.00 | 36.52 | E | C |
| ATOM | 7136 | O | LEU | E | 348 | −21.387 | 44.397 | 79.796 | 1.00 | 36.28 | E | O |
| ATOM | 7137 | N | LYS | E | 349 | −23.109 | 43.272 | 80.713 | 1.00 | 37.94 | E | N |
| ATOM | 7138 | CA | LYS | E | 349 | −23.525 | 44.365 | 81.585 | 1.00 | 38.99 | E | C |
| ATOM | 7139 | CB | LYS | E | 349 | −22.324 | 44.833 | 82.428 | 1.00 | 41.12 | E | C |
| ATOM | 7140 | CG | LYS | E | 349 | −22.519 | 46.137 | 83.201 | 1.00 | 46.53 | E | C |
| ATOM | 7141 | CD | LYS | E | 349 | −21.585 | 47.243 | 82.683 | 1.00 | 49.62 | E | C |
| ATOM | 7142 | CE | LYS | E | 349 | −22.273 | 48.612 | 82.667 | 1.00 | 51.48 | E | C |
| ATOM | 7143 | NZ | LYS | E | 349 | −22.844 | 48.988 | 83.999 | 1.00 | 53.58 | E | N |
| ATOM | 7144 | C | LYS | E | 349 | −24.131 | 45.533 | 80.799 | 1.00 | 38.05 | E | C |
| ATOM | 7145 | O | LYS | E | 349 | −23.760 | 46.691 | 80.994 | 1.00 | 37.15 | E | O |
| ATOM | 7146 | N | LEU | E | 350 | −25.067 | 45.233 | 79.901 | 1.00 | 36.29 | E | N |
| ATOM | 7147 | CA | LEU | E | 350 | −25.705 | 46.295 | 79.131 | 1.00 | 34.93 | E | C |
| ATOM | 7148 | CB | LEU | E | 350 | −24.953 | 46.576 | 77.822 | 1.00 | 35.24 | E | C |
| ATOM | 7149 | CG | LEU | E | 350 | −23.522 | 46.102 | 77.584 | 1.00 | 35.58 | E | C |
| ATOM | 7150 | CD1 | LEU | E | 350 | −23.406 | 45.507 | 76.187 | 1.00 | 35.10 | E | C |
| ATOM | 7151 | CD2 | LEU | E | 350 | −22.572 | 47.279 | 77.739 | 1.00 | 34.88 | E | C |
| ATOM | 7152 | C | LEU | E | 350 | −27.136 | 45.979 | 78.770 | 1.00 | 34.35 | E | C |
| ATOM | 7153 | O | LEU | E | 350 | −27.554 | 44.823 | 78.779 | 1.00 | 34.68 | E | O |
| ATOM | 7154 | N | HIS | E | 351 | −27.891 | 47.026 | 78.468 | 1.00 | 34.55 | E | N |
| ATOM | 7155 | CA | HIS | E | 351 | −29.258 | 46.853 | 78.021 | 1.00 | 36.34 | E | C |
| ATOM | 7156 | CB | HIS | E | 351 | −30.268 | 47.480 | 78.972 | 1.00 | 37.42 | E | C |
| ATOM | 7157 | CG | HIS | E | 351 | −31.676 | 47.072 | 78.673 | 1.00 | 40.56 | E | C |
| ATOM | 7158 | CD2 | HIS | E | 351 | −32.525 | 47.460 | 77.692 | 1.00 | 41.30 | E | C |
| ATOM | 7159 | ND1 | HIS | E | 351 | −32.329 | 46.080 | 79.374 | 1.00 | 40.99 | E | N |
| ATOM | 7160 | CE1 | HIS | E | 351 | −33.519 | 45.876 | 78.839 | 1.00 | 41.26 | E | C |
| ATOM | 7161 | NE2 | HIS | E | 351 | −33.663 | 46.701 | 77.817 | 1.00 | 41.85 | E | N |
| ATOM | 7162 | C | HIS | E | 351 | −29.346 | 47.529 | 76.660 | 1.00 | 35.16 | E | C |
| ATOM | 7163 | O | HIS | E | 351 | −29.235 | 48.747 | 76.553 | 1.00 | 34.85 | E | O |
| ATOM | 7164 | N | PRO | E | 352 | −29.530 | 46.734 | 75.601 | 1.00 | 34.77 | E | N |
| ATOM | 7165 | CD | PRO | E | 352 | −29.660 | 45.269 | 75.645 | 1.00 | 34.15 | E | C |
| ATOM | 7166 | CA | PRO | E | 352 | −29.626 | 47.251 | 74.235 | 1.00 | 35.00 | E | C |
| ATOM | 7167 | CB | PRO | E | 352 | −30.322 | 46.124 | 73.460 | 1.00 | 35.61 | E | C |
| ATOM | 7168 | CG | PRO | E | 352 | −30.457 | 44.966 | 74.426 | 1.00 | 35.38 | E | C |
| ATOM | 7169 | C | PRO | E | 352 | −30.371 | 48.576 | 74.105 | 1.00 | 34.84 | E | C |
| ATOM | 7170 | O | PRO | E | 352 | −29.978 | 49.440 | 73.319 | 1.00 | 34.88 | E | O |
| ATOM | 7171 | N | TYR | E | 353 | −31.433 | 48.743 | 74.889 | 1.00 | 33.28 | E | N |
| ATOM | 7172 | CA | TYR | E | 353 | −32.235 | 49.959 | 74.815 | 1.00 | 31.96 | E | C |
| ATOM | 7173 | CB | TYR | E | 353 | −33.568 | 49.741 | 75.532 | 1.00 | 33.06 | E | C |
| ATOM | 7174 | CG | TYR | E | 353 | −34.431 | 48.678 | 74.877 | 1.00 | 34.89 | E | C |
| ATOM | 7175 | CD1 | TYR | E | 353 | −34.078 | 48.125 | 73.638 | 1.00 | 35.70 | E | C |
| ATOM | 7176 | CE1 | TYR | E | 353 | −34.855 | 47.137 | 73.037 | 1.00 | 35.51 | E | C |
| ATOM | 7177 | CD2 | TYR | E | 353 | −35.589 | 48.212 | 75.497 | 1.00 | 35.31 | E | C |
| ATOM | 7178 | CE2 | TYR | E | 353 | −36.378 | 47.219 | 74.902 | 1.00 | 36.12 | E | C |
| ATOM | 7179 | CZ | TYR | E | 353 | −36.004 | 46.686 | 73.673 | 1.00 | 37.80 | E | C |
| ATOM | 7180 | OH | TYR | E | 353 | −36.775 | 45.705 | 73.084 | 1.00 | 38.26 | E | O |
| ATOM | 7181 | C | TYR | E | 353 | −31.562 | 51.226 | 75.321 | 1.00 | 30.43 | E | C |
| ATOM | 7182 | O | TYR | E | 353 | −31.996 | 52.331 | 74.987 | 1.00 | 30.48 | E | O |
| ATOM | 7183 | N | ASP | E | 354 | −30.502 | 51.075 | 76.112 | 1.00 | 30.09 | E | N |
| ATOM | 7184 | CA | ASP | E | 354 | −29.765 | 52.233 | 76.633 | 1.00 | 28.48 | E | C |
| ATOM | 7185 | CB | ASP | E | 354 | −29.164 | 51.925 | 78.005 | 1.00 | 31.52 | E | C |
| ATOM | 7186 | CG | ASP | E | 354 | −30.214 | 51.565 | 79.036 | 1.00 | 35.30 | E | C |
| ATOM | 7187 | OD1 | ASP | E | 354 | −31.341 | 52.100 | 78.947 | 1.00 | 35.33 | E | O |
| ATOM | 7188 | OD2 | ASP | E | 354 | −29.911 | 50.746 | 79.932 | 1.00 | 35.95 | E | O |
| ATOM | 7189 | C | ASP | E | 354 | −28.639 | 52.614 | 75.685 | 1.00 | 25.42 | E | C |
| ATOM | 7190 | O | ASP | E | 354 | −28.020 | 53.666 | 75.832 | 1.00 | 25.22 | E | O |
| ATOM | 7191 | N | LEU | E | 355 | −28.378 | 51.744 | 74.714 | 1.00 | 24.15 | E | N |
| ATOM | 7192 | CA | LEU | E | 355 | −27.322 | 51.977 | 73.747 | 1.00 | 21.69 | E | C |
| ATOM | 7193 | CB | LEU | E | 355 | −27.221 | 50.799 | 72.785 | 1.00 | 20.89 | E | C |
| ATOM | 7194 | CG | LEU | E | 355 | −26.515 | 49.602 | 73.430 | 1.00 | 21.67 | E | C |
| ATOM | 7195 | CD1 | LEU | E | 355 | −26.525 | 48.416 | 72.482 | 1.00 | 21.23 | E | C |
| ATOM | 7196 | CD2 | LEU | E | 355 | −25.088 | 49.987 | 73.800 | 1.00 | 19.40 | E | C |
| ATOM | 7197 | C | LEU | E | 355 | −27.534 | 53.270 | 72.990 | 1.00 | 20.82 | E | C |
| ATOM | 7198 | O | LEU | E | 355 | −28.656 | 53.701 | 72.758 | 1.00 | 20.07 | E | O |
| ATOM | 7199 | N | THR | E | 356 | −26.423 | 53.878 | 72.611 | 1.00 | 20.86 | E | N |
| ATOM | 7200 | CA | THR | E | 356 | −26.403 | 55.144 | 71.905 | 1.00 | 20.58 | E | C |
| ATOM | 7201 | CB | THR | E | 356 | −26.078 | 56.249 | 72.937 | 1.00 | 21.84 | E | C |
| ATOM | 7202 | OG1 | THR | E | 356 | −27.298 | 56.750 | 73.494 | 1.00 | 24.77 | E | O |
| ATOM | 7203 | CG2 | THR | E | 356 | −25.307 | 57.370 | 72.331 | 1.00 | 23.56 | E | C |
| ATOM | 7204 | C | THR | E | 356 | −25.282 | 54.994 | 70.871 | 1.00 | 20.22 | E | C |
| ATOM | 7205 | O | THR | E | 356 | −24.537 | 54.014 | 70.933 | 1.00 | 20.80 | E | O |
| ATOM | 7206 | N | VAL | E | 357 | −25.155 | 55.904 | 69.905 | 1.00 | 19.80 | E | N |
| ATOM | 7207 | CA | VAL | E | 357 | −24.040 | 55.757 | 68.967 | 1.00 | 19.24 | E | C |
| ATOM | 7208 | CB | VAL | E | 357 | −24.127 | 56.725 | 67.727 | 1.00 | 20.26 | E | C |
| ATOM | 7209 | CG1 | VAL | E | 357 | −25.453 | 56.523 | 66.997 | 1.00 | 18.46 | E | C |
| ATOM | 7210 | CG2 | VAL | E | 357 | −23.952 | 58.169 | 68.149 | 1.00 | 21.79 | E | C |
| ATOM | 7211 | C | VAL | E | 357 | −22.755 | 56.024 | 69.763 | 1.00 | 17.55 | E | C |
| ATOM | 7212 | O | VAL | E | 357 | −21.686 | 55.526 | 69.416 | 1.00 | 16.77 | E | O |
| ATOM | 7213 | N | ASP | E | 358 | −22.877 | 56.791 | 70.850 | 1.00 | 17.43 | E | N |
| ATOM | 7214 | CA | ASP | E | 358 | −21.737 | 57.095 | 71.716 | 1.00 | 17.86 | E | C |
| ATOM | 7215 | CB | ASP | E | 358 | −22.128 | 58.093 | 72.804 | 1.00 | 21.13 | E | C |
| ATOM | 7216 | CG | ASP | E | 358 | −22.344 | 59.494 | 72.272 | 1.00 | 24.43 | E | C |
| ATOM | 7217 | OD1 | ASP | E | 358 | −21.720 | 59.858 | 71.245 | 1.00 | 24.32 | E | O |
| ATOM | 7218 | OD2 | ASP | E | 358 | −23.144 | 60.231 | 72.897 | 1.00 | 26.10 | E | O |
| ATOM | 7219 | C | ASP | E | 358 | −21.245 | 55.819 | 72.391 | 1.00 | 17.21 | E | C |
| ATOM | 7220 | O | ASP | E | 358 | −20.044 | 55.544 | 72.415 | 1.00 | 17.65 | E | O |
| ATOM | 7221 | N | SER | E | 359 | −22.176 | 55.045 | 72.950 | 1.00 | 18.12 | E | N |
| ATOM | 7222 | CA | SER | E | 359 | −21.826 | 53.794 | 73.625 | 1.00 | 18.58 | E | C |
| ATOM | 7223 | CB | SER | E | 359 | −22.941 | 53.368 | 74.584 | 1.00 | 18.19 | E | C |
| ATOM | 7224 | OG | SER | E | 359 | −24.222 | 53.627 | 74.041 | 1.00 | 18.40 | E | O |
| ATOM | 7225 | C | SER | E | 359 | −21.551 | 52.681 | 72.611 | 1.00 | 19.68 | E | C |
| ATOM | 7226 | O | SER | E | 359 | −20.771 | 51.759 | 72.878 | 1.00 | 18.62 | E | O |
| ATOM | 7227 | N | LEU | E | 360 | −22.197 | 52.758 | 71.449 | 1.00 | 21.04 | E | N |
| ATOM | 7228 | CA | LEU | E | 360 | −21.967 | 51.771 | 70.399 | 1.00 | 21.20 | E | C |
| ATOM | 7229 | CB | LEU | E | 360 | −22.839 | 52.072 | 69.181 | 1.00 | 20.53 | E | C |
| ATOM | 7230 | CG | LEU | E | 360 | −22.613 | 51.145 | 67.982 | 1.00 | 21.23 | E | C |
| ATOM | 7231 | CD1 | LEU | E | 360 | −22.891 | 49.685 | 68.384 | 1.00 | 20.56 | E | C |
| ATOM | 7232 | CD2 | LEU | E | 360 | −23.519 | 51.579 | 66.833 | 1.00 | 20.16 | E | C |
| ATOM | 7233 | C | LEU | E | 360 | −20.486 | 51.862 | 70.023 | 1.00 | 21.26 | E | C |
| ATOM | 7234 | O | LEU | E | 360 | −19.844 | 50.857 | 69.726 | 1.00 | 22.05 | E | O |
| ATOM | 7235 | N | ASP | E | 361 | −19.964 | 53.087 | 70.029 | 1.00 | 22.76 | E | N |
| ATOM | 7236 | CA | ASP | E | 361 | −18.554 | 53.361 | 69.750 | 1.00 | 23.78 | E | C |
| ATOM | 7237 | CB | ASP | E | 361 | −17.740 | 53.063 | 71.022 | 1.00 | 24.70 | E | C |
| ATOM | 7238 | CG | ASP | E | 361 | −16.483 | 53.920 | 71.144 | 1.00 | 25.97 | E | C |
| ATOM | 7239 | OD1 | ASP | E | 361 | −16.435 | 55.030 | 70.566 | 1.00 | 27.28 | E | O |
| ATOM | 7240 | OD2 | ASP | E | 361 | −15.537 | 53.478 | 71.828 | 1.00 | 23.76 | E | O |
| ATOM | 7241 | C | ASP | E | 361 | −17.919 | 52.633 | 68.556 | 1.00 | 24.87 | E | C |
| ATOM | 7242 | O | ASP | E | 361 | −16.827 | 52.072 | 68.684 | 1.00 | 25.78 | E | O |
| ATOM | 7243 | N | VAL | E | 362 | −18.571 | 52.653 | 67.395 | 1.00 | 25.36 | E | N |
| ATOM | 7244 | CA | VAL | E | 362 | −18.006 | 51.985 | 66.223 | 1.00 | 25.93 | E | C |
| ATOM | 7245 | CB | VAL | E | 362 | −19.049 | 51.090 | 65.512 | 1.00 | 25.12 | E | C |
| ATOM | 7246 | CG1 | VAL | E | 362 | −19.477 | 49.959 | 66.438 | 1.00 | 23.48 | E | C |
| ATOM | 7247 | CG2 | VAL | E | 362 | −20.241 | 51.918 | 65.069 | 1.00 | 24.89 | E | C |
| ATOM | 7248 | C | VAL | E | 362 | −17.432 | 52.975 | 65.211 | 1.00 | 26.79 | E | C |
| ATOM | 7249 | O | VAL | E | 362 | −16.831 | 52.580 | 64.212 | 1.00 | 28.45 | E | O |
| ATOM | 7250 | N | HIS | E | 363 | −17.605 | 54.261 | 65.482 | 1.00 | 27.79 | E | N |
| ATOM | 7251 | CA | HIS | E | 363 | −17.105 | 55.313 | 64.605 | 1.00 | 30.45 | E | C |
| ATOM | 7252 | CB | HIS | E | 363 | −17.947 | 56.576 | 64.777 | 1.00 | 31.67 | E | C |
| ATOM | 7253 | CG | HIS | E | 363 | −18.026 | 57.431 | 63.550 | 1.00 | 33.46 | E | C |
| ATOM | 7254 | CD2 | HIS | E | 363 | −18.897 | 57.424 | 62.511 | 1.00 | 33.47 | E | C |
| ATOM | 7255 | ND1 | HIS | E | 363 | −17.149 | 58.469 | 63.307 | 1.00 | 35.31 | E | N |
| ATOM | 7256 | CE1 | HIS | E | 363 | −17.478 | 59.063 | 62.174 | 1.00 | 35.51 | E | C |
| ATOM | 7257 | NE2 | HIS | E | 363 | −18.535 | 58.449 | 61.672 | 1.00 | 34.04 | E | N |
| ATOM | 7258 | C | HIS | E | 363 | −15.653 | 55.636 | 64.927 | 1.00 | 32.04 | E | C |
| ATOM | 7259 | O | HIS | E | 363 | −15.299 | 55.819 | 66.092 | 1.00 | 31.62 | E | O |
| ATOM | 7260 | N | ALA | E | 364 | −14.818 | 55.705 | 63.893 | 1.00 | 33.75 | E | N |
| ATOM | 7261 | CA | ALA | E | 364 | −13.405 | 56.018 | 64.069 | 1.00 | 36.37 | E | C |
| ATOM | 7262 | CB | ALA | E | 364 | −12.637 | 55.675 | 62.803 | 1.00 | 35.43 | E | C |
| ATOM | 7263 | C | ALA | E | 364 | −13.247 | 57.502 | 64.398 | 1.00 | 38.94 | E | C |
| ATOM | 7264 | O | ALA | E | 364 | −13.877 | 58.357 | 63.779 | 1.00 | 40.26 | E | O |
| ATOM | 7265 | N | GLY | E | 365 | −12.409 | 57.814 | 65.378 | 1.00 | 41.03 | E | N |
| ATOM | 7266 | CA | GLY | E | 365 | −12.223 | 59.206 | 65.743 | 1.00 | 43.14 | E | C |
| ATOM | 7267 | C | GLY | E | 365 | −10.823 | 59.706 | 65.464 | 1.00 | 44.14 | E | C |
| ATOM | 7268 | O | GLY | E | 365 | −10.122 | 59.164 | 64.603 | 1.00 | 46.69 | E | O |
| ATOM | 7269 | N | ARG | E | 366 | −10.420 | 60.747 | 66.186 | 1.00 | 44.27 | E | N |
| ATOM | 7270 | CA | ARG | E | 366 | −9.092 | 61.327 | 66.032 | 1.00 | 44.96 | E | C |
| ATOM | 7271 | CB | ARG | E | 366 | −8.904 | 62.478 | 67.015 | 1.00 | 45.11 | E | C |
| ATOM | 7272 | CG | ARG | E | 366 | −10.176 | 63.280 | 67.210 | 1.00 | 44.62 | E | C |
| ATOM | 7273 | CD | ARG | E | 366 | −9.931 | 64.757 | 67.050 | 1.00 | 44.46 | E | C |
| ATOM | 7274 | NE | ARG | E | 366 | −10.578 | 65.469 | 68.139 | 1.00 | 42.93 | E | N |
| ATOM | 7275 | CZ | ARG | E | 366 | −10.067 | 65.550 | 69.358 | 1.00 | 45.23 | E | C |
| ATOM | 7276 | NH1 | ARG | E | 366 | −8.905 | 64.966 | 69.627 | 1.00 | 45.89 | E | N |
| ATOM | 7277 | NH2 | ARG | E | 366 | −10.734 | 66.179 | 70.315 | 1.00 | 45.25 | E | N |
| ATOM | 7278 | C | ARG | E | 366 | −8.075 | 60.237 | 66.294 | 1.00 | 45.34 | E | C |
| ATOM | 7279 | O | ARG | E | 366 | −6.975 | 60.239 | 65.730 | 1.00 | 45.98 | E | O |
| ATOM | 7280 | N | GLN | E | 367 | −8.441 | 59.303 | 67.163 | 1.00 | 47.19 | E | N |
| ATOM | 7281 | CA | GLN | E | 367 | −7.570 | 58.177 | 67.454 | 1.00 | 49.47 | E | C |
| ATOM | 7282 | CB | GLN | E | 367 | −7.976 | 57.523 | 68.775 | 1.00 | 53.50 | E | C |
| ATOM | 7283 | CG | GLN | E | 367 | −7.759 | 56.019 | 68.828 | 1.00 | 58.79 | E | C |
| ATOM | 7284 | CD | GLN | E | 367 | −8.998 | 55.268 | 69.297 | 1.00 | 61.57 | E | C |
| ATOM | 7285 | OE1 | GLN | E | 367 | −9.675 | 55.694 | 70.246 | 1.00 | 63.16 | E | O |
| ATOM | 7286 | NE2 | GLN | E | 367 | −9.303 | 54.144 | 68.639 | 1.00 | 62.14 | E | N |
| ATOM | 7287 | C | GLN | E | 367 | −7.792 | 57.228 | 66.275 | 1.00 | 49.21 | E | C |
| ATOM | 7288 | O | GLN | E | 367 | −8.640 | 57.498 | 65.424 | 1.00 | 51.28 | E | O |
| ATOM | 7289 | N | THR | E | 368 | −7.052 | 56.124 | 66.232 | 1.00 | 47.54 | E | N |
| ATOM | 7290 | CA | THR | E | 368 | −7.131 | 55.146 | 65.133 | 1.00 | 45.44 | E | C |
| ATOM | 7291 | CB | THR | E | 368 | −8.605 | 54.856 | 64.599 | 1.00 | 44.33 | E | C |
| ATOM | 7292 | OG1 | THR | E | 368 | −8.988 | 55.855 | 63.648 | 1.00 | 42.55 | E | O |
| ATOM | 7293 | CG2 | THR | E | 368 | −9.626 | 54.808 | 65.742 | 1.00 | 43.79 | E | C |
| ATOM | 7294 | C | THR | E | 368 | −6.272 | 55.654 | 63.968 | 1.00 | 43.41 | E | C |
| ATOM | 7295 | O | THR | E | 368 | −5.828 | 54.860 | 63.130 | 1.00 | 42.51 | E | O |
| ATOM | 7296 | N | PHE | E | 369 | −6.037 | 56.971 | 63.919 | 1.00 | 40.23 | E | N |
| ATOM | 7297 | CA | PHE | E | 369 | −5.200 | 57.542 | 62.870 | 1.00 | 38.35 | E | C |
| ATOM | 7298 | CB | PHE | E | 369 | −5.102 | 59.067 | 62.982 | 1.00 | 36.49 | E | C |
| ATOM | 7299 | CG | PHE | E | 369 | −4.373 | 59.719 | 61.826 | 1.00 | 35.81 | E | C |
| ATOM | 7300 | CD1 | PHE | E | 369 | −5.020 | 59.946 | 60.609 | 1.00 | 35.35 | E | C |
| ATOM | 7301 | CD2 | PHE | E | 369 | −3.036 | 60.096 | 61.950 | 1.00 | 35.35 | E | C |
| ATOM | 7302 | CE1 | PHE | E | 369 | −4.340 | 60.540 | 59.529 | 1.00 | 33.93 | E | C |
| ATOM | 7303 | CE2 | PHE | E | 369 | −2.349 | 60.691 | 60.877 | 1.00 | 34.80 | E | C |
| ATOM | 7304 | CZ | PHE | E | 369 | −3.004 | 60.911 | 59.667 | 1.00 | 34.19 | E | C |
| ATOM | 7305 | C | PHE | E | 369 | −3.829 | 56.932 | 63.087 | 1.00 | 38.39 | E | C |
| ATOM | 7306 | O | PHE | E | 369 | −3.153 | 57.244 | 64.069 | 1.00 | 37.77 | E | O |
| ATOM | 7307 | N | GLN | E | 370 | −3.437 | 56.051 | 62.170 | 1.00 | 39.14 | E | N |
| ATOM | 7308 | CA | GLN | E | 370 | −2.162 | 55.349 | 62.243 | 1.00 | 38.17 | E | C |
| ATOM | 7309 | CB | GLN | E | 370 | −1.004 | 56.337 | 62.288 | 1.00 | 38.01 | E | C |
| ATOM | 7310 | CG | GLN | E | 370 | −0.181 | 56.335 | 61.026 | 1.00 | 39.01 | E | C |
| ATOM | 7311 | CD | GLN | E | 370 | 0.084 | 57.734 | 60.540 | 1.00 | 41.23 | E | C |
| ATOM | 7312 | OE1 | GLN | E | 370 | −0.259 | 58.707 | 61.216 | 1.00 | 42.41 | E | O |
| ATOM | 7313 | NE2 | GLN | E | 370 | 0.696 | 57.853 | 59.363 | 1.00 | 41.51 | E | N |
| ATOM | 7314 | C | GLN | E | 370 | −2.133 | 54.437 | 63.469 | 1.00 | 38.26 | E | C |
| ATOM | 7315 | O | GLN | E | 370 | −1.081 | 54.198 | 64.068 | 1.00 | 38.49 | E | O |
| ATOM | 7316 | N | ARG | E | 371 | −3.316 | 53.947 | 63.834 | 1.00 | 37.70 | E | N |
| ATOM | 7317 | CA | ARG | E | 371 | −3.495 | 53.029 | 64.953 | 1.00 | 36.76 | E | C |
| ATOM | 7318 | CB | ARG | E | 371 | −4.165 | 53.723 | 66.145 | 1.00 | 34.88 | E | C |
| ATOM | 7319 | CG | ARG | E | 371 | −3.203 | 54.505 | 67.031 | 1.00 | 36.92 | E | C |
| ATOM | 7320 | CD | ARG | E | 371 | −2.167 | 53.604 | 67.712 | 1.00 | 36.68 | E | C |
| ATOM | 7321 | NE | ARG | E | 371 | −2.747 | 52.392 | 68.303 | 1.00 | 37.63 | E | N |
| ATOM | 7322 | CZ | ARG | E | 371 | −3.141 | 52.270 | 69.574 | 1.00 | 38.17 | E | C |
| ATOM | 7323 | NH1 | ARG | E | 371 | −3.031 | 53.286 | 70.420 | 1.00 | 37.96 | E | N |
| ATOM | 7324 | NH2 | ARG | E | 371 | −3.647 | 51.122 | 70.013 | 1.00 | 37.51 | E | N |
| ATOM | 7325 | C | ARG | E | 371 | −4.420 | 51.966 | 64.391 | 1.00 | 37.12 | E | C |
| ATOM | 7326 | O | ARG | E | 371 | −5.587 | 51.868 | 64.787 | 1.00 | 37.76 | E | O |
| ATOM | 7327 | N | PHE | E | 372 | −3.895 | 51.188 | 63.447 | 1.00 | 35.94 | E | N |
| ATOM | 7328 | CA | PHE | E | 372 | −4.673 | 50.142 | 62.804 | 1.00 | 35.70 | E | C |
| ATOM | 7329 | CB | PHE | E | 372 | −3.783 | 49.298 | 61.887 | 1.00 | 33.50 | E | C |
| ATOM | 7330 | CG | PHE | E | 372 | −4.534 | 48.663 | 60.760 | 1.00 | 33.21 | E | C |
| ATOM | 7331 | CD1 | PHE | E | 372 | −4.721 | 49.349 | 59.559 | 1.00 | 32.28 | E | C |
| ATOM | 7332 | CD2 | PHE | E | 372 | −5.112 | 47.405 | 60.917 | 1.00 | 30.69 | E | C |
| ATOM | 7333 | CE1 | PHE | E | 372 | −5.479 | 48.795 | 58.535 | 1.00 | 32.56 | E | C |
| ATOM | 7334 | CE2 | PHE | E | 372 | −5.872 | 46.839 | 59.900 | 1.00 | 31.06 | E | C |
| ATOM | 7335 | CZ | PHE | E | 372 | −6.058 | 47.532 | 58.707 | 1.00 | 32.57 | E | C |
| ATOM | 7336 | C | PHE | E | 372 | −5.378 | 49.235 | 63.808 | 1.00 | 35.94 | E | C |
| ATOM | 7337 | O | PHE | E | 372 | −6.520 | 48.820 | 63.593 | 1.00 | 36.46 | E | O |
| ATOM | 7338 | N | ASP | E | 373 | −4.691 | 48.928 | 64.903 | 1.00 | 36.35 | E | N |
| ATOM | 7339 | CA | ASP | E | 373 | −5.249 | 48.078 | 65.946 | 1.00 | 37.69 | E | C |
| ATOM | 7340 | CB | ASP | E | 373 | −4.243 | 47.932 | 67.086 | 1.00 | 38.33 | E | C |
| ATOM | 7341 | CG | ASP | E | 373 | −3.617 | 49.258 | 67.482 | 1.00 | 41.02 | E | C |
| ATOM | 7342 | OD1 | ASP | E | 373 | −3.938 | 50.292 | 66.851 | 1.00 | 40.75 | E | O |
| ATOM | 7343 | OD2 | ASP | E | 373 | −2.800 | 49.261 | 68.428 | 1.00 | 42.67 | E | O |
| ATOM | 7344 | C | ASP | E | 373 | −6.556 | 48.660 | 66.489 | 1.00 | 37.74 | E | C |
| ATOM | 7345 | O | ASP | E | 373 | −7.512 | 47.925 | 66.764 | 1.00 | 38.03 | E | O |
| ATOM | 7346 | N | LYS | E | 374 | −6.594 | 49.982 | 66.637 | 1.00 | 37.02 | E | N |
| ATOM | 7347 | CA | LYS | E | 374 | −7.779 | 50.658 | 67.145 | 1.00 | 36.95 | E | C |
| ATOM | 7348 | CB | LYS | E | 374 | −7.415 | 52.059 | 67.629 | 1.00 | 37.59 | E | C |
| ATOM | 7349 | CG | LYS | E | 374 | −6.314 | 52.050 | 68.667 | 1.00 | 39.96 | E | C |
| ATOM | 7350 | CD | LYS | E | 374 | −6.195 | 53.382 | 69.364 | 1.00 | 40.73 | E | C |
| ATOM | 7351 | CE | LYS | E | 374 | −6.889 | 53.351 | 70.711 | 1.00 | 41.80 | E | C |
| ATOM | 7352 | NZ | LYS | E | 374 | −6.504 | 54.533 | 71.537 | 1.00 | 43.68 | E | N |
| ATOM | 7353 | C | LYS | E | 374 | −8.856 | 50.738 | 66.078 | 1.00 | 37.64 | E | C |
| ATOM | 7354 | O | LYS | E | 374 | −10.039 | 50.907 | 66.386 | 1.00 | 38.10 | E | O |
| ATOM | 7355 | N | PHE | E | 375 | −8.446 | 50.624 | 64.819 | 1.00 | 38.04 | E | N |
| ATOM | 7356 | CA | PHE | E | 375 | −9.401 | 50.661 | 63.716 | 1.00 | 37.24 | E | C |
| ATOM | 7357 | CB | PHE | E | 375 | −8.688 | 50.955 | 62.389 | 1.00 | 34.59 | E | C |
| ATOM | 7358 | CG | PHE | E | 375 | −9.439 | 50.456 | 61.188 | 1.00 | 34.81 | E | C |
| ATOM | 7359 | CD1 | PHE | E | 375 | −10.631 | 51.069 | 60.800 | 1.00 | 34.39 | E | C |
| ATOM | 7360 | CD2 | PHE | E | 375 | −9.003 | 49.328 | 60.493 | 1.00 | 33.56 | E | C |
| ATOM | 7361 | CE1 | PHE | E | 375 | −11.387 | 50.564 | 59.744 | 1.00 | 32.93 | E | C |
| ATOM | 7362 | CE2 | PHE | E | 375 | −9.750 | 48.814 | 59.437 | 1.00 | 32.98 | E | C |
| ATOM | 7363 | CZ | PHE | E | 375 | −10.948 | 49.437 | 59.065 | 1.00 | 33.13 | E | C |
| ATOM | 7364 | C | PHE | E | 375 | −10.114 | 49.298 | 63.630 | 1.00 | 37.35 | E | C |
| ATOM | 7365 | O | PHE | E | 375 | −11.344 | 49.226 | 63.488 | 1.00 | 35.79 | E | O |
| ATOM | 7366 | N | ASN | E | 376 | −9.332 | 48.225 | 63.727 | 1.00 | 38.46 | E | N |
| ATOM | 7367 | CA | ASN | E | 376 | −9.876 | 46.876 | 63.658 | 1.00 | 41.54 | E | C |
| ATOM | 7368 | CB | ASN | E | 376 | −8.742 | 45.860 | 63.520 | 1.00 | 41.57 | E | C |
| ATOM | 7369 | CG | ASN | E | 376 | −8.990 | 44.868 | 62.403 | 1.00 | 43.81 | E | C |
| ATOM | 7370 | OD1 | ASN | E | 376 | −10.137 | 44.638 | 62.000 | 1.00 | 44.60 | E | O |
| ATOM | 7371 | ND2 | ASN | E | 376 | −7.918 | 44.276 | 61.890 | 1.00 | 43.71 | E | N |
| ATOM | 7372 | C | ASN | E | 376 | −10.743 | 46.519 | 64.870 | 1.00 | 42.99 | E | C |
| ATOM | 7373 | O | ASN | E | 376 | −11.678 | 45.718 | 64.770 | 1.00 | 43.39 | E | O |
| ATOM | 7374 | N | ASP | E | 377 | −10.437 | 47.107 | 66.017 | 1.00 | 43.77 | E | N |
| ATOM | 7375 | CA | ASP | E | 377 | −11.230 | 46.817 | 67.191 | 1.00 | 46.33 | E | C |
| ATOM | 7376 | CB | ASP | E | 377 | −10.380 | 46.970 | 68.450 | 1.00 | 48.96 | E | C |
| ATOM | 7377 | CG | ASP | E | 377 | −9.675 | 45.667 | 68.825 | 1.00 | 51.79 | E | C |
| ATOM | 7378 | OD1 | ASP | E | 377 | −9.700 | 44.716 | 68.004 | 1.00 | 51.94 | E | O |
| ATOM | 7379 | OD2 | ASP | E | 377 | −9.100 | 45.592 | 69.935 | 1.00 | 55.22 | E | O |
| ATOM | 7380 | C | ASP | E | 377 | −12.463 | 47.709 | 67.219 | 1.00 | 46.35 | E | C |
| ATOM | 7381 | O | ASP | E | 377 | −13.269 | 47.653 | 68.145 | 1.00 | 46.13 | E | O |
| ATOM | 7382 | N | LYS | E | 378 | −12.613 | 48.522 | 66.178 | 1.00 | 48.06 | E | N |
| ATOM | 7383 | CA | LYS | E | 378 | −13.769 | 49.400 | 66.053 | 1.00 | 48.22 | E | C |
| ATOM | 7384 | CB | LYS | E | 378 | −13.486 | 50.519 | 65.049 | 1.00 | 49.37 | E | C |
| ATOM | 7385 | CG | LYS | E | 378 | −13.986 | 51.883 | 65.484 | 1.00 | 51.27 | E | C |
| ATOM | 7386 | CD | LYS | E | 378 | −13.047 | 52.511 | 66.498 | 1.00 | 52.11 | E | C |
| ATOM | 7387 | CE | LYS | E | 378 | −13.811 | 53.076 | 67.677 | 1.00 | 51.97 | E | C |
| ATOM | 7388 | NZ | LYS | E | 378 | −13.461 | 54.503 | 67.896 | 1.00 | 55.22 | E | N |
| ATOM | 7389 | C | LYS | E | 378 | −14.914 | 48.531 | 65.546 | 1.00 | 47.99 | E | C |
| ATOM | 7390 | O | LYS | E | 378 | −16.086 | 48.904 | 65.628 | 1.00 | 47.71 | E | O |
| ATOM | 7391 | N | TYR | E | 379 | −14.552 | 47.364 | 65.015 | 1.00 | 48.23 | E | N |
| ATOM | 7392 | CA | TYR | E | 379 | −15.525 | 46.411 | 64.499 | 1.00 | 47.49 | E | C |
| ATOM | 7393 | CB | TYR | E | 379 | −14.829 | 45.312 | 63.698 | 1.00 | 51.38 | E | C |
| ATOM | 7394 | CG | TYR | E | 379 | −14.577 | 45.648 | 62.248 | 1.00 | 56.52 | E | C |
| ATOM | 7395 | CD1 | TYR | E | 379 | −13.431 | 45.188 | 61.600 | 1.00 | 57.82 | E | C |
| ATOM | 7396 | CE1 | TYR | E | 379 | −13.191 | 45.488 | 60.266 | 1.00 | 59.01 | E | C |
| ATOM | 7397 | CD2 | TYR | E | 379 | −15.481 | 46.423 | 61.520 | 1.00 | 57.54 | E | C |
| ATOM | 7398 | CE2 | TYR | E | 379 | −15.248 | 46.729 | 60.182 | 1.00 | 58.82 | E | C |
| ATOM | 7399 | CZ | TYR | E | 379 | −14.103 | 46.259 | 59.560 | 1.00 | 59.21 | E | C |
| ATOM | 7400 | OH | TYR | E | 379 | −13.874 | 46.550 | 58.233 | 1.00 | 58.05 | E | O |
| ATOM | 7401 | C | TYR | E | 379 | −16.257 | 45.772 | 65.667 | 1.00 | 45.68 | E | C |
| ATOM | 7402 | O | TYR | E | 379 | −17.160 | 44.956 | 65.472 | 1.00 | 46.61 | E | O |
| ATOM | 7403 | N | ASN | E | 380 | −15.848 | 46.134 | 66.882 | 1.00 | 41.93 | E | N |
| ATOM | 7404 | CA | ASN | E | 380 | −16.463 | 45.601 | 68.092 | 1.00 | 36.63 | E | C |
| ATOM | 7405 | CB | ASN | E | 380 | −15.411 | 45.385 | 69.180 | 1.00 | 34.83 | E | C |
| ATOM | 7406 | CG | ASN | E | 380 | −14.420 | 44.307 | 68.821 | 1.00 | 33.91 | E | C |
| ATOM | 7407 | OD1 | ASN | E | 380 | −14.737 | 43.374 | 68.086 | 1.00 | 31.95 | E | O |
| ATOM | 7408 | ND2 | ASN | E | 380 | −13.207 | 44.429 | 69.340 | 1.00 | 34.55 | E | N |
| ATOM | 7409 | C | ASN | E | 380 | −17.523 | 46.555 | 68.621 | 1.00 | 33.32 | E | C |
| ATOM | 7410 | O | ASN | E | 380 | −17.202 | 47.569 | 69.238 | 1.00 | 33.05 | E | O |
| ATOM | 7411 | N | PRO | E | 381 | −18.805 | 46.247 | 68.376 | 1.00 | 30.19 | E | N |
| ATOM | 7412 | CD | PRO | E | 381 | −19.332 | 45.080 | 67.651 | 1.00 | 29.50 | E | C |
| ATOM | 7413 | CA | PRO | E | 381 | −19.868 | 47.126 | 68.869 | 1.00 | 29.09 | E | C |
| ATOM | 7414 | CB | PRO | E | 381 | −21.155 | 46.435 | 68.418 | 1.00 | 28.02 | E | C |
| ATOM | 7415 | CG | PRO | E | 381 | −20.741 | 45.470 | 67.365 | 1.00 | 27.58 | E | C |
| ATOM | 7416 | C | PRO | E | 381 | −19.772 | 47.226 | 70.395 | 1.00 | 28.85 | E | C |
| ATOM | 7417 | O | PRO | E | 381 | −19.558 | 46.223 | 71.079 | 1.00 | 27.21 | E | O |
| ATOM | 7418 | N | VAL | E | 382 | −19.924 | 48.438 | 70.915 | 1.00 | 28.24 | E | N |
| ATOM | 7419 | CA | VAL | E | 382 | −19.847 | 48.689 | 72.349 | 1.00 | 28.57 | E | C |
| ATOM | 7420 | CB | VAL | E | 382 | −21.143 | 48.210 | 73.073 | 1.00 | 28.64 | E | C |
| ATOM | 7421 | CG1 | VAL | E | 382 | −21.035 | 46.759 | 73.464 | 1.00 | 31.39 | E | C |
| ATOM | 7422 | CG2 | VAL | E | 382 | −21.392 | 49.063 | 74.299 | 1.00 | 30.18 | E | C |
| ATOM | 7423 | C | VAL | E | 382 | −18.603 | 48.050 | 72.979 | 1.00 | 28.26 | E | C |
| ATOM | 7424 | O | VAL | E | 382 | −18.576 | 47.753 | 74.171 | 1.00 | 28.25 | E | O |
| ATOM | 7425 | N | GLY | E | 383 | −17.573 | 47.850 | 72.158 | 1.00 | 27.18 | E | N |
| ATOM | 7426 | CA | GLY | E | 383 | −16.321 | 47.280 | 72.629 | 1.00 | 23.55 | E | C |
| ATOM | 7427 | C | GLY | E | 383 | −16.316 | 45.799 | 72.944 | 1.00 | 23.01 | E | C |
| ATOM | 7428 | O | GLY | E | 383 | −15.358 | 45.302 | 73.531 | 1.00 | 23.50 | E | O |
| ATOM | 7429 | N | ALA | E | 384 | −17.365 | 45.085 | 72.550 | 1.00 | 23.03 | E | N |
| ATOM | 7430 | CA | ALA | E | 384 | −17.457 | 43.652 | 72.827 | 1.00 | 22.27 | E | C |
| ATOM | 7431 | CB | ALA | E | 384 | −18.804 | 43.338 | 73.470 | 1.00 | 20.42 | E | C |
| ATOM | 7432 | C | ALA | E | 384 | −17.269 | 42.789 | 71.584 | 1.00 | 22.96 | E | C |
| ATOM | 7433 | O | ALA | E | 384 | −18.069 | 42.850 | 70.653 | 1.00 | 23.47 | E | O |
| ATOM | 7434 | N | SER | E | 385 | −16.222 | 41.972 | 71.577 | 1.00 | 23.79 | E | N |
| ATOM | 7435 | CA | SER | E | 385 | −15.966 | 41.092 | 70.448 | 1.00 | 24.30 | E | C |
| ATOM | 7436 | CB | SER | E | 385 | −14.640 | 40.351 | 70.644 | 1.00 | 25.65 | E | C |
| ATOM | 7437 | OG | SER | E | 385 | −14.782 | 39.242 | 71.512 | 1.00 | 29.97 | E | O |
| ATOM | 7438 | C | SER | E | 385 | −17.116 | 40.100 | 70.286 | 1.00 | 25.45 | E | C |
| ATOM | 7439 | O | SER | E | 385 | −17.403 | 39.648 | 69.177 | 1.00 | 26.52 | E | O |
| ATOM | 7440 | N | GLU | E | 386 | −17.777 | 39.774 | 71.397 | 1.00 | 25.61 | E | N |
| ATOM | 7441 | CA | GLU | E | 386 | −18.914 | 38.852 | 71.393 | 1.00 | 25.25 | E | C |
| ATOM | 7442 | CB | GLU | E | 386 | −19.480 | 38.686 | 72.809 | 1.00 | 25.13 | E | C |
| ATOM | 7443 | CG | GLU | E | 386 | −18.607 | 37.884 | 73.762 | 1.00 | 26.05 | E | C |
| ATOM | 7444 | CD | GLU | E | 386 | −17.604 | 38.746 | 74.514 | 1.00 | 26.82 | E | C |
| ATOM | 7445 | OE1 | GLU | E | 386 | −16.782 | 38.182 | 75.267 | 1.00 | 27.83 | E | O |
| ATOM | 7446 | OE2 | GLU | E | 386 | −17.631 | 39.986 | 74.354 | 1.00 | 28.94 | E | O |
| ATOM | 7447 | C | GLU | E | 386 | −20.015 | 39.397 | 70.492 | 1.00 | 25.01 | E | C |
| ATOM | 7448 | O | GLU | E | 386 | −20.679 | 38.643 | 69.785 | 1.00 | 25.97 | E | O |
| ATOM | 7449 | N | LEU | E | 387 | −20.206 | 40.712 | 70.531 | 1.00 | 25.16 | E | N |
| ATOM | 7450 | CA | LEU | E | 387 | −21.234 | 41.368 | 69.729 | 1.00 | 24.87 | E | C |
| ATOM | 7451 | CB | LEU | E | 387 | −21.525 | 42.755 | 70.302 | 1.00 | 25.20 | E | C |
| ATOM | 7452 | CG | LEU | E | 387 | −22.130 | 42.750 | 71.712 | 1.00 | 24.99 | E | C |
| ATOM | 7453 | CD1 | LEU | E | 387 | −22.440 | 44.166 | 72.136 | 1.00 | 25.11 | E | C |
| ATOM | 7454 | CD2 | LEU | E | 387 | −23.401 | 41.910 | 71.737 | 1.00 | 25.47 | E | C |
| ATOM | 7455 | C | LEU | E | 387 | −20.835 | 41.466 | 68.258 | 1.00 | 25.14 | E | C |
| ATOM | 7456 | O | LEU | E | 387 | −21.687 | 41.466 | 67.374 | 1.00 | 24.44 | E | O |
| ATOM | 7457 | N | ARG | E | 388 | −19.537 | 41.551 | 68.000 | 1.00 | 25.59 | E | N |
| ATOM | 7458 | CA | ARG | E | 388 | −19.052 | 41.598 | 66.632 | 1.00 | 27.86 | E | C |
| ATOM | 7459 | CB | ARG | E | 388 | −17.556 | 41.930 | 66.600 | 1.00 | 30.71 | E | C |
| ATOM | 7460 | CG | ARG | E | 388 | −16.803 | 41.331 | 65.419 | 1.00 | 35.14 | E | C |
| ATOM | 7461 | CD | ARG | E | 388 | −15.652 | 42.218 | 64.973 | 1.00 | 40.10 | E | C |
| ATOM | 7462 | NE | ARG | E | 388 | −14.824 | 41.570 | 63.956 | 1.00 | 46.79 | E | N |
| ATOM | 7463 | CZ | ARG | E | 388 | −13.608 | 41.982 | 63.592 | 1.00 | 49.49 | E | C |
| ATOM | 7464 | NH1 | ARG | E | 388 | −13.059 | 43.050 | 64.159 | 1.00 | 50.69 | E | N |
| ATOM | 7465 | NH2 | ARG | E | 388 | −12.932 | 41.316 | 62.664 | 1.00 | 51.88 | E | N |
| ATOM | 7466 | C | ARG | E | 388 | −19.292 | 40.213 | 66.036 | 1.00 | 26.67 | E | C |
| ATOM | 7467 | O | ARG | E | 388 | −19.798 | 40.080 | 64.923 | 1.00 | 27.49 | E | O |
| ATOM | 7468 | N | ASP | E | 389 | −18.934 | 39.184 | 66.792 | 1.00 | 25.10 | E | N |
| ATOM | 7469 | CA | ASP | E | 389 | −19.110 | 37.807 | 66.364 | 1.00 | 23.91 | E | C |
| ATOM | 7470 | CB | ASP | E | 389 | −18.636 | 36.847 | 67.438 | 1.00 | 26.44 | E | C |
| ATOM | 7471 | CG | ASP | E | 389 | −17.136 | 36.763 | 67.523 | 1.00 | 29.53 | E | C |
| ATOM | 7472 | OD1 | ASP | E | 389 | −16.633 | 36.160 | 68.495 | 1.00 | 31.18 | E | O |
| ATOM | 7473 | OD2 | ASP | E | 389 | −16.458 | 37.300 | 66.620 | 1.00 | 32.61 | E | O |
| ATOM | 7474 | C | ASP | E | 389 | −20.558 | 37.485 | 66.050 | 1.00 | 22.29 | E | C |
| ATOM | 7475 | O | ASP | E | 389 | −20.852 | 36.691 | 65.159 | 1.00 | 21.93 | E | O |
| ATOM | 7476 | N | LEU | E | 390 | −21.457 | 38.104 | 66.804 | 1.00 | 21.43 | E | N |
| ATOM | 7477 | CA | LEU | E | 390 | −22.881 | 37.863 | 66.666 | 1.00 | 21.24 | E | C |
| ATOM | 7478 | CB | LEU | E | 390 | −23.568 | 38.165 | 68.003 | 1.00 | 20.20 | E | C |
| ATOM | 7479 | CG | LEU | E | 390 | −25.097 | 38.124 | 68.058 | 1.00 | 20.50 | E | C |
| ATOM | 7480 | CD1 | LEU | E | 390 | −25.587 | 36.722 | 67.733 | 1.00 | 21.71 | E | C |
| ATOM | 7481 | CD2 | LEU | E | 390 | −25.569 | 38.543 | 69.443 | 1.00 | 22.00 | E | C |
| ATOM | 7482 | C | LEU | E | 390 | −23.601 | 38.613 | 65.545 | 1.00 | 21.24 | E | C |
| ATOM | 7483 | O | LEU | E | 390 | −24.416 | 38.029 | 64.826 | 1.00 | 21.76 | E | O |
| ATOM | 7484 | N | TYR | E | 391 | −23.297 | 39.897 | 65.395 | 1.00 | 20.23 | E | N |
| ATOM | 7485 | CA | TYR | E | 391 | −23.962 | 40.736 | 64.401 | 1.00 | 20.56 | E | C |
| ATOM | 7486 | CB | TYR | E | 391 | −24.296 | 42.100 | 65.030 | 1.00 | 20.41 | E | C |
| ATOM | 7487 | CG | TYR | E | 391 | −25.338 | 42.059 | 66.136 | 1.00 | 22.96 | E | C |
| ATOM | 7488 | CD1 | TYR | E | 391 | −26.702 | 42.040 | 65.838 | 1.00 | 23.34 | E | C |
| ATOM | 7489 | CE1 | TYR | E | 391 | −27.660 | 41.996 | 66.845 | 1.00 | 22.64 | E | C |
| ATOM | 7490 | CD2 | TYR | E | 391 | −24.959 | 42.037 | 67.481 | 1.00 | 23.47 | E | C |
| ATOM | 7491 | CE2 | TYR | E | 391 | −25.915 | 41.991 | 68.498 | 1.00 | 22.85 | E | C |
| ATOM | 7492 | CZ | TYR | E | 391 | −27.260 | 41.969 | 68.171 | 1.00 | 22.23 | E | C |
| ATOM | 7493 | OH | TYR | E | 391 | −28.206 | 41.900 | 69.165 | 1.00 | 22.21 | E | O |
| ATOM | 7494 | C | TYR | E | 391 | −23.215 | 40.987 | 63.089 | 1.00 | 20.22 | E | C |
| ATOM | 7495 | O | TYR | E | 391 | −23.837 | 41.310 | 62.071 | 1.00 | 18.30 | E | O |
| ATOM | 7496 | N | LEU | E | 392 | −21.892 | 40.843 | 63.110 | 1.00 | 19.26 | E | N |
| ATOM | 7497 | CA | LEU | E | 392 | −21.091 | 41.131 | 61.928 | 1.00 | 19.23 | E | C |
| ATOM | 7498 | CB | LEU | E | 392 | −20.216 | 42.366 | 62.192 | 1.00 | 17.55 | E | C |
| ATOM | 7499 | CG | LEU | E | 392 | −20.927 | 43.575 | 62.810 | 1.00 | 19.39 | E | C |
| ATOM | 7500 | CD1 | LEU | E | 392 | −19.912 | 44.642 | 63.168 | 1.00 | 18.17 | E | C |
| ATOM | 7501 | CD2 | LEU | E | 392 | −21.958 | 44.126 | 61.840 | 1.00 | 17.42 | E | C |
| ATOM | 7502 | C | LEU | E | 392 | −20.213 | 40.010 | 61.403 | 1.00 | 20.12 | E | C |
| ATOM | 7503 | O | LEU | E | 392 | −19.168 | 40.273 | 60.802 | 1.00 | 20.71 | E | O |
| ATOM | 7504 | N | LYS | E | 393 | −20.623 | 38.766 | 61.614 | 1.00 | 19.95 | E | N |
| ATOM | 7505 | CA | LYS | E | 393 | −19.844 | 37.639 | 61.126 | 1.00 | 20.51 | E | C |
| ATOM | 7506 | CB | LYS | E | 393 | −19.110 | 36.959 | 62.273 | 1.00 | 21.81 | E | C |
| ATOM | 7507 | CG | LYS | E | 393 | −17.980 | 37.790 | 62.830 | 1.00 | 24.34 | E | C |
| ATOM | 7508 | CD | LYS | E | 393 | −16.700 | 36.997 | 62.858 | 1.00 | 28.06 | E | C |
| ATOM | 7509 | CE | LYS | E | 393 | −15.595 | 37.776 | 63.539 | 1.00 | 30.86 | E | C |
| ATOM | 7510 | NZ | LYS | E | 393 | −14.364 | 36.946 | 63.677 | 1.00 | 33.83 | E | N |
| ATOM | 7511 | C | LYS | E | 393 | −20.767 | 36.651 | 60.451 | 1.00 | 20.98 | E | C |
| ATOM | 7512 | O | LYS | E | 393 | −21.963 | 36.627 | 60.730 | 1.00 | 20.77 | E | O |
| ATOM | 7513 | N | THR | E | 394 | −20.213 | 35.839 | 59.558 | 1.00 | 20.11 | E | N |
| ATOM | 7514 | CA | THR | E | 394 | −21.021 | 34.862 | 58.843 | 1.00 | 21.18 | E | C |
| ATOM | 7515 | CB | THR | E | 394 | −20.493 | 34.665 | 57.394 | 1.00 | 19.15 | E | C |
| ATOM | 7516 | OG1 | THR | E | 394 | −19.173 | 34.113 | 57.427 | 1.00 | 17.16 | E | O |
| ATOM | 7517 | CG2 | THR | E | 394 | −20.452 | 35.988 | 56.664 | 1.00 | 15.15 | E | C |
| ATOM | 7518 | C | THR | E | 394 | −21.065 | 33.513 | 59.568 | 1.00 | 22.50 | E | C |
| ATOM | 7519 | O | THR | E | 394 | −22.034 | 32.758 | 59.442 | 1.00 | 22.71 | E | O |
| ATOM | 7520 | N | ASP | E | 395 | −20.020 | 33.223 | 60.337 | 1.00 | 23.00 | E | N |
| ATOM | 7521 | CA | ASP | E | 395 | −19.948 | 31.972 | 61.068 | 1.00 | 25.34 | E | C |
| ATOM | 7522 | CB | ASP | E | 395 | −18.641 | 31.251 | 60.753 | 1.00 | 28.41 | E | C |
| ATOM | 7523 | CG | ASP | E | 395 | −18.624 | 29.822 | 61.272 | 1.00 | 33.02 | E | C |
| ATOM | 7524 | OD1 | ASP | E | 395 | −19.711 | 29.207 | 61.370 | 1.00 | 35.71 | E | O |
| ATOM | 7525 | OD2 | ASP | E | 395 | −17.524 | 29.313 | 61.580 | 1.00 | 35.97 | E | O |
| ATOM | 7526 | C | ASP | E | 395 | −20.056 | 32.183 | 62.572 | 1.00 | 26.00 | E | C |
| ATOM | 7527 | O | ASP | E | 395 | −19.198 | 32.815 | 63.179 | 1.00 | 24.99 | E | O |
| ATOM | 7528 | N | ASN | E | 396 | −21.120 | 31.652 | 63.163 | 1.00 | 26.31 | E | N |
| ATOM | 7529 | CA | ASN | E | 396 | −21.338 | 31.763 | 64.594 | 1.00 | 25.76 | E | C |
| ATOM | 7530 | CB | ASN | E | 396 | −21.704 | 33.203 | 64.980 | 1.00 | 23.25 | E | C |
| ATOM | 7531 | CG | ASN | E | 396 | −22.993 | 33.676 | 64.351 | 1.00 | 23.35 | E | C |
| ATOM | 7532 | OD1 | ASN | E | 396 | −23.251 | 34.875 | 64.287 | 1.00 | 25.12 | E | O |
| ATOM | 7533 | ND2 | ASN | E | 396 | −23.812 | 32.743 | 63.887 | 1.00 | 23.78 | E | N |
| ATOM | 7534 | C | ASN | E | 396 | −22.430 | 30.799 | 65.027 | 1.00 | 26.59 | E | C |
| ATOM | 7535 | O | ASN | E | 396 | −22.889 | 29.974 | 64.236 | 1.00 | 27.10 | E | O |
| ATOM | 7536 | N | TYR | E | 397 | −22.847 | 30.909 | 66.283 | 1.00 | 27.02 | E | N |
| ATOM | 7537 | CA | TYR | E | 397 | −23.865 | 30.024 | 66.824 | 1.00 | 26.99 | E | C |
| ATOM | 7538 | CB | TYR | E | 397 | −24.130 | 30.350 | 68.293 | 1.00 | 29.26 | E | C |
| ATOM | 7539 | CG | TYR | E | 397 | −24.913 | 29.271 | 68.999 | 1.00 | 29.89 | E | C |
| ATOM | 7540 | CD1 | TYR | E | 397 | −26.306 | 29.326 | 69.068 | 1.00 | 29.27 | E | C |
| ATOM | 7541 | CE1 | TYR | E | 397 | −27.035 | 28.324 | 69.703 | 1.00 | 31.17 | E | C |
| ATOM | 7542 | CD2 | TYR | E | 397 | −24.262 | 28.185 | 69.586 | 1.00 | 31.64 | E | C |
| ATOM | 7543 | CE2 | TYR | E | 397 | −24.981 | 27.174 | 70.226 | 1.00 | 33.45 | E | C |
| ATOM | 7544 | CZ | TYR | E | 397 | −26.367 | 27.249 | 70.281 | 1.00 | 33.03 | E | C |
| ATOM | 7545 | OH | TYR | E | 397 | −27.080 | 26.250 | 70.913 | 1.00 | 37.18 | E | O |
| ATOM | 7546 | C | TYR | E | 397 | −25.175 | 30.051 | 66.056 | 1.00 | 26.79 | E | C |
| ATOM | 7547 | O | TYR | E | 397 | −25.841 | 29.024 | 65.938 | 1.00 | 28.08 | E | O |
| ATOM | 7548 | N | ILE | E | 398 | −25.563 | 31.216 | 65.548 | 1.00 | 26.06 | E | N |
| ATOM | 7549 | CA | ILE | E | 398 | −26.803 | 31.301 | 64.789 | 1.00 | 25.61 | E | C |
| ATOM | 7550 | CB | ILE | E | 398 | −27.656 | 32.526 | 65.214 | 1.00 | 25.24 | E | C |
| ATOM | 7551 | CG2 | ILE | E | 398 | −28.215 | 32.298 | 66.601 | 1.00 | 25.73 | E | C |
| ATOM | 7552 | CG1 | ILE | E | 398 | −26.820 | 33.802 | 65.203 | 1.00 | 24.54 | E | C |
| ATOM | 7553 | CD1 | ILE | E | 398 | −27.658 | 35.053 | 65.165 | 1.00 | 24.22 | E | C |
| ATOM | 7554 | C | ILE | E | 398 | −26.546 | 31.342 | 63.281 | 1.00 | 25.08 | E | C |
| ATOM | 7555 | O | ILE | E | 398 | −27.362 | 31.852 | 62.516 | 1.00 | 25.76 | E | O |
| ATOM | 7556 | N | ASN | E | 399 | −25.407 | 30.792 | 62.867 | 1.00 | 25.29 | E | N |
| ATOM | 7557 | CA | ASN | E | 399 | −25.014 | 30.720 | 61.459 | 1.00 | 26.12 | E | C |
| ATOM | 7558 | CB | ASN | E | 399 | −25.879 | 29.686 | 60.732 | 1.00 | 27.65 | E | C |
| ATOM | 7559 | CG | ASN | E | 399 | −25.872 | 28.326 | 61.418 | 1.00 | 30.40 | E | C |
| ATOM | 7560 | OD1 | ASN | E | 399 | −24.815 | 27.797 | 61.769 | 1.00 | 30.64 | E | O |
| ATOM | 7561 | ND2 | ASN | E | 399 | −27.057 | 27.755 | 61.609 | 1.00 | 30.12 | E | N |
| ATOM | 7562 | C | ASN | E | 399 | −25.068 | 32.044 | 60.693 | 1.00 | 26.38 | E | C |
| ATOM | 7563 | O | ASN | E | 399 | −25.641 | 32.114 | 59.604 | 1.00 | 27.11 | E | O |
| ATOM | 7564 | N | GLY | E | 400 | −24.472 | 33.086 | 61.264 | 1.00 | 25.27 | E | N |
| ATOM | 7565 | CA | GLY | E | 400 | −24.439 | 34.390 | 60.623 | 1.00 | 23.36 | E | C |
| ATOM | 7566 | C | GLY | E | 400 | −25.755 | 34.991 | 60.160 | 1.00 | 22.66 | E | C |
| ATOM | 7567 | O | GLY | E | 400 | −25.767 | 35.879 | 59.311 | 1.00 | 21.48 | E | O |
| ATOM | 7568 | N | GLU | E | 401 | −26.863 | 34.541 | 60.729 | 1.00 | 23.18 | E | N |
| ATOM | 7569 | CA | GLU | E | 401 | −28.172 | 35.043 | 60.336 | 1.00 | 23.31 | E | C |
| ATOM | 7570 | CB | GLU | E | 401 | −29.251 | 34.267 | 61.083 | 1.00 | 23.96 | E | C |
| ATOM | 7571 | CG | GLU | E | 401 | −30.648 | 34.757 | 60.791 | 1.00 | 27.51 | E | C |
| ATOM | 7572 | CD | GLU | E | 401 | −31.679 | 34.069 | 61.652 | 1.00 | 29.41 | E | C |
| ATOM | 7573 | OE1 | GLU | E | 401 | −31.653 | 32.817 | 61.707 | 1.00 | 29.58 | E | O |
| ATOM | 7574 | OE2 | GLU | E | 401 | −32.508 | 34.778 | 62.270 | 1.00 | 27.66 | E | O |
| ATOM | 7575 | C | GLU | E | 401 | −28.407 | 36.552 | 60.512 | 1.00 | 23.77 | E | C |
| ATOM | 7576 | O | GLU | E | 401 | −29.095 | 37.177 | 59.699 | 1.00 | 23.67 | E | O |
| ATOM | 7577 | N | TYR | E | 402 | −27.852 | 37.136 | 61.573 | 1.00 | 24.14 | E | N |
| ATOM | 7578 | CA | TYR | E | 402 | −28.016 | 38.569 | 61.847 | 1.00 | 21.45 | E | C |
| ATOM | 7579 | CB | TYR | E | 402 | −27.524 | 38.900 | 63.260 | 1.00 | 21.72 | E | C |
| ATOM | 7580 | CG | TYR | E | 402 | −28.507 | 38.565 | 64.365 | 1.00 | 21.77 | E | C |
| ATOM | 7581 | CD1 | TYR | E | 402 | −29.743 | 38.002 | 64.074 | 1.00 | 22.05 | E | C |
| ATOM | 7582 | CE1 | TYR | E | 402 | −30.666 | 37.716 | 65.084 | 1.00 | 23.91 | E | C |
| ATOM | 7583 | CD2 | TYR | E | 402 | −28.207 | 38.836 | 65.702 | 1.00 | 21.41 | E | C |
| ATOM | 7584 | CE2 | TYR | E | 402 | −29.121 | 38.555 | 66.722 | 1.00 | 21.72 | E | C |
| ATOM | 7585 | CZ | TYR | E | 402 | −30.349 | 37.998 | 66.404 | 1.00 | 22.83 | E | C |
| ATOM | 7586 | OH | TYR | E | 402 | −31.271 | 37.740 | 67.388 | 1.00 | 21.84 | E | O |
| ATOM | 7587 | C | TYR | E | 402 | −27.260 | 39.429 | 60.834 | 1.00 | 19.80 | E | C |
| ATOM | 7588 | O | TYR | E | 402 | −27.738 | 40.490 | 60.425 | 1.00 | 16.76 | E | O |
| ATOM | 7589 | N | PHE | E | 403 | −26.072 | 38.968 | 60.453 | 1.00 | 18.60 | E | N |
| ATOM | 7590 | CA | PHE | E | 403 | −25.241 | 39.663 | 59.477 | 1.00 | 19.49 | E | C |
| ATOM | 7591 | CB | PHE | E | 403 | −23.886 | 38.967 | 59.358 | 1.00 | 17.82 | E | C |
| ATOM | 7592 | CG | PHE | E | 403 | −22.873 | 39.751 | 58.585 | 1.00 | 18.17 | E | C |
| ATOM | 7593 | CD1 | PHE | E | 403 | −22.902 | 41.146 | 58.584 | 1.00 | 15.49 | E | C |
| ATOM | 7594 | CD2 | PHE | E | 403 | −21.888 | 39.097 | 57.855 | 1.00 | 16.24 | E | C |
| ATOM | 7595 | CE1 | PHE | E | 403 | −21.958 | 41.877 | 57.862 | 1.00 | 18.55 | E | C |
| ATOM | 7596 | CE2 | PHE | E | 403 | −20.939 | 39.816 | 57.129 | 1.00 | 17.47 | E | C |
| ATOM | 7597 | CZ | PHE | E | 403 | −20.971 | 41.207 | 57.130 | 1.00 | 16.77 | E | C |
| ATOM | 7598 | C | PHE | E | 403 | −25.956 | 39.632 | 58.131 | 1.00 | 18.84 | E | C |
| ATOM | 7599 | O | PHE | E | 403 | −25.991 | 40.623 | 57.408 | 1.00 | 20.08 | E | O |
| ATOM | 7600 | N | ALA | E | 404 | −26.537 | 38.482 | 57.815 | 1.00 | 19.84 | E | N |
| ATOM | 7601 | CA | ALA | E | 404 | −27.273 | 38.307 | 56.576 | 1.00 | 19.65 | E | C |
| ATOM | 7602 | CB | ALA | E | 404 | −27.807 | 36.896 | 56.493 | 1.00 | 18.12 | E | C |
| ATOM | 7603 | C | ALA | E | 404 | −28.420 | 39.305 | 56.512 | 1.00 | 20.07 | E | C |
| ATOM | 7604 | O | ALA | E | 404 | −28.577 | 40.029 | 55.529 | 1.00 | 22.37 | E | O |
| ATOM | 7605 | N | THR | E | 405 | −29.214 | 39.352 | 57.573 | 1.00 | 20.00 | E | N |
| ATOM | 7606 | CA | THR | E | 405 | −30.357 | 40.255 | 57.635 | 1.00 | 19.19 | E | C |
| ATOM | 7607 | CB | THR | E | 405 | −31.130 | 40.071 | 58.949 | 1.00 | 18.52 | E | C |
| ATOM | 7608 | OG1 | THR | E | 405 | −31.443 | 38.685 | 59.121 | 1.00 | 19.23 | E | O |
| ATOM | 7609 | CG2 | THR | E | 405 | −32.418 | 40.883 | 58.926 | 1.00 | 17.29 | E | C |
| ATOM | 7610 | C | THR | E | 405 | −30.000 | 41.732 | 57.488 | 1.00 | 19.87 | E | C |
| ATOM | 7611 | O | THR | E | 405 | −30.712 | 42.476 | 56.812 | 1.00 | 20.60 | E | O |
| ATOM | 7612 | N | ILE | E | 406 | −28.918 | 42.159 | 58.134 | 1.00 | 20.93 | E | N |
| ATOM | 7613 | CA | ILE | E | 406 | −28.488 | 43.556 | 58.053 | 1.00 | 22.01 | E | C |
| ATOM | 7614 | CB | ILE | E | 406 | −27.286 | 43.856 | 58.991 | 1.00 | 22.19 | E | C |
| ATOM | 7615 | CD2 | ILE | E | 406 | −26.768 | 45.268 | 58.738 | 1.00 | 23.78 | E | C |
| ATOM | 7616 | CG1 | ILE | E | 406 | −27.712 | 43.737 | 60.457 | 1.00 | 23.54 | E | C |
| ATOM | 7617 | CD1 | ILE | E | 406 | −26.539 | 43.654 | 61.431 | 1.00 | 20.18 | E | C |
| ATOM | 7618 | C | ILE | E | 406 | −28.059 | 43.860 | 56.621 | 1.00 | 21.76 | E | C |
| ATOM | 7619 | O | ILE | E | 406 | −28.441 | 44.885 | 56.049 | 1.00 | 22.88 | E | O |
| ATOM | 7620 | N | ILE | E | 407 | −27.262 | 42.960 | 56.050 | 1.00 | 21.21 | E | N |
| ATOM | 7621 | CA | ILE | E | 407 | −26.781 | 43.117 | 54.685 | 1.00 | 20.15 | E | C |
| ATOM | 7622 | CB | ILE | E | 407 | −25.867 | 41.957 | 54.295 | 1.00 | 18.07 | E | C |
| ATOM | 7623 | CG2 | ILE | E | 407 | −25.985 | 41.670 | 52.814 | 1.00 | 18.28 | E | C |
| ATOM | 7624 | CG1 | ILE | E | 407 | −24.428 | 42.305 | 54.649 | 1.00 | 18.44 | E | C |
| ATOM | 7625 | CD1 | ILE | E | 407 | −23.535 | 41.101 | 54.733 | 1.00 | 20.00 | E | C |
| ATOM | 7626 | C | ILE | E | 407 | −27.944 | 43.202 | 53.694 | 1.00 | 20.85 | E | C |
| ATOM | 7627 | O | ILE | E | 407 | −27.932 | 44.027 | 52.784 | 1.00 | 20.87 | E | O |
| ATOM | 7628 | N | LYS | E | 408 | −28.957 | 42.365 | 53.881 | 1.00 | 20.87 | E | N |
| ATOM | 7629 | CA | LYS | E | 408 | −30.098 | 42.378 | 52.982 | 1.00 | 20.59 | E | C |
| ATOM | 7630 | CB | LYS | E | 408 | −31.006 | 41.179 | 53.254 | 1.00 | 20.89 | E | C |
| ATOM | 7631 | CG | LYS | E | 408 | −30.535 | 39.909 | 52.568 | 1.00 | 20.91 | E | C |
| ATOM | 7632 | CD | LYS | E | 408 | −30.560 | 38.725 | 53.508 | 1.00 | 23.74 | E | C |
| ATOM | 7633 | CE | LYS | E | 408 | −31.841 | 37.937 | 53.352 | 1.00 | 24.87 | E | C |
| ATOM | 7634 | NZ | LYS | E | 408 | −32.463 | 38.193 | 52.019 | 1.00 | 28.45 | E | N |
| ATOM | 7635 | C | LYS | E | 408 | −30.880 | 43.676 | 53.112 | 1.00 | 21.84 | E | C |
| ATOM | 7636 | O | LYS | E | 408 | −31.495 | 44.144 | 52.146 | 1.00 | 20.78 | E | O |
| ATOM | 7637 | N | GLU | E | 409 | −30.851 | 44.261 | 54.305 | 1.00 | 20.17 | E | N |
| ATOM | 7638 | CA | GLU | E | 409 | −31.552 | 45.514 | 54.537 | 1.00 | 21.31 | E | C |
| ATOM | 7639 | CB | GLU | E | 409 | −31.663 | 45.787 | 56.038 | 1.00 | 23.77 | E | C |
| ATOM | 7640 | CG | GLU | E | 409 | −32.631 | 44.861 | 56.751 | 1.00 | 25.03 | E | C |
| ATOM | 7641 | CD | GLU | E | 409 | −32.807 | 45.208 | 58.215 | 1.00 | 26.00 | E | C |
| ATOM | 7642 | OE1 | GLU | E | 409 | −31.949 | 45.921 | 58.777 | 1.00 | 25.96 | E | O |
| ATOM | 7643 | OE2 | GLU | E | 409 | −33.810 | 44.760 | 58.802 | 1.00 | 28.39 | E | O |
| ATOM | 7644 | C | GLU | E | 409 | −30.804 | 46.651 | 53.847 | 1.00 | 19.63 | E | C |
| ATOM | 7645 | O | GLU | E | 409 | −31.404 | 47.624 | 53.390 | 1.00 | 19.70 | E | O |
| ATOM | 7646 | N | VAL | E | 410 | −29.488 | 46.526 | 53.782 | 1.00 | 18.24 | E | N |
| ATOM | 7647 | CA | VAL | E | 410 | −28.669 | 47.532 | 53.128 | 1.00 | 19.36 | E | C |
| ATOM | 7648 | CB | VAL | E | 410 | −27.170 | 47.277 | 53.367 | 1.00 | 19.65 | E | C |
| ATOM | 7649 | CG1 | VAL | E | 410 | −26.348 | 48.193 | 52.483 | 1.00 | 19.86 | E | C |
| ATOM | 7650 | CG2 | VAL | E | 410 | −26.823 | 47.496 | 54.831 | 1.00 | 18.14 | E | C |
| ATOM | 7651 | C | VAL | E | 410 | −28.945 | 47.456 | 51.624 | 1.00 | 20.92 | E | C |
| ATOM | 7652 | O | VAL | E | 410 | −29.189 | 48.471 | 50.977 | 1.00 | 20.87 | E | O |
| ATOM | 7653 | N | GLY | E | 411 | −28.911 | 46.238 | 51.084 | 1.00 | 21.09 | E | N |
| ATOM | 7654 | CA | GLY | E | 411 | −29.163 | 46.038 | 49.669 | 1.00 | 21.03 | E | C |
| ATOM | 7655 | C | GLY | E | 411 | −30.500 | 46.606 | 49.240 | 1.00 | 22.00 | E | C |
| ATOM | 7656 | O | GLY | E | 411 | −30.622 | 47.190 | 48.161 | 1.00 | 24.57 | E | O |
| ATOM | 7657 | N | ALA | E | 412 | −31.512 | 46.444 | 50.085 | 1.00 | 21.96 | E | N |
| ATOM | 7658 | CA | ALA | E | 412 | −32.840 | 46.948 | 49.774 | 1.00 | 21.09 | E | C |
| ATOM | 7659 | CB | ALA | E | 412 | −33.844 | 46.439 | 50.797 | 1.00 | 20.89 | E | C |
| ATOM | 7660 | C | ALA | E | 412 | −32.854 | 48.471 | 49.737 | 1.00 | 21.69 | E | C |
| ATOM | 7661 | O | ALA | E | 412 | −33.583 | 49.075 | 48.950 | 1.00 | 21.59 | E | O |
| ATOM | 7662 | N | ASP | E | 413 | −32.058 | 49.100 | 50.596 | 1.00 | 21.52 | E | N |
| ATOM | 7663 | CA | ASP | E | 413 | −32.002 | 50.557 | 50.616 | 1.00 | 21.70 | E | C |
| ATOM | 7664 | CB | ASP | E | 413 | −31.139 | 51.050 | 51.780 | 1.00 | 23.09 | E | C |
| ATOM | 7665 | CG | ASP | E | 413 | −31.884 | 51.068 | 53.101 | 1.00 | 24.18 | E | C |
| ATOM | 7666 | OD1 | ASP | E | 413 | −31.208 | 51.054 | 54.153 | 1.00 | 23.47 | E | O |
| ATOM | 7667 | OD2 | ASP | E | 413 | −33.133 | 51.095 | 53.088 | 1.00 | 22.61 | E | O |
| ATOM | 7668 | C | ASP | E | 413 | −31.378 | 51.017 | 49.307 | 1.00 | 22.03 | E | C |
| ATOM | 7669 | O | ASP | E | 413 | −31.741 | 52.059 | 48.765 | 1.00 | 21.89 | E | O |
| ATOM | 7670 | N | LEU | E | 414 | −30.424 | 50.228 | 48.821 | 1.00 | 22.04 | E | N |
| ATOM | 7671 | CA | LEU | E | 414 | −29.716 | 50.507 | 47.578 | 1.00 | 20.69 | E | C |
| ATOM | 7672 | CB | LEU | E | 414 | −28.617 | 49.455 | 47.368 | 1.00 | 20.52 | E | C |
| ATOM | 7673 | CG | LEU | E | 414 | −27.145 | 49.815 | 47.613 | 1.00 | 18.93 | E | C |
| ATOM | 7674 | CD1 | LEU | E | 414 | −27.022 | 51.036 | 48.482 | 1.00 | 17.91 | E | C |
| ATOM | 7675 | CD2 | LEU | E | 414 | −26.448 | 48.636 | 48.246 | 1.00 | 16.97 | E | C |
| ATOM | 7676 | C | LEU | E | 414 | −30.701 | 50.472 | 46.412 | 1.00 | 20.59 | E | C |
| ATOM | 7677 | O | LEU | E | 414 | −30.762 | 51.405 | 45.613 | 1.00 | 19.22 | E | O |
| ATOM | 7678 | N | VAL | E | 415 | −31.474 | 49.391 | 46.332 | 1.00 | 21.88 | E | N |
| ATOM | 7679 | CA | VAL | E | 415 | −32.467 | 49.221 | 45.277 | 1.00 | 22.80 | E | C |
| ATOM | 7680 | CB | VAL | E | 415 | −33.234 | 47.888 | 45.445 | 1.00 | 22.03 | E | C |
| ATOM | 7681 | CG1 | VAL | E | 415 | −34.452 | 47.864 | 44.541 | 1.00 | 21.47 | E | C |
| ATOM | 7682 | CG2 | VAL | E | 415 | −32.324 | 46.723 | 45.112 | 1.00 | 18.57 | E | C |
| ATOM | 7683 | C | VAL | E | 415 | −33.470 | 50.371 | 45.255 | 1.00 | 24.47 | E | C |
| ATOM | 7684 | O | VAL | E | 415 | −33.981 | 50.734 | 44.197 | 1.00 | 24.67 | E | O |
| ATOM | 7685 | N | ASP | E | 416 | −33.748 | 50.944 | 46.422 | 1.00 | 26.14 | E | N |
| ATOM | 7686 | CA | ASP | E | 416 | −34.689 | 52.059 | 46.528 | 1.00 | 28.06 | E | C |
| ATOM | 7687 | CB | ASP | E | 416 | −35.045 | 52.326 | 47.990 | 1.00 | 32.15 | E | C |
| ATOM | 7688 | CG | ASP | E | 416 | −36.190 | 51.473 | 48.476 | 1.00 | 38.14 | E | C |
| ATOM | 7689 | OD1 | ASP | E | 416 | −36.446 | 51.481 | 49.699 | 1.00 | 42.28 | E | O |
| ATOM | 7690 | OD2 | ASP | E | 416 | −36.834 | 50.792 | 47.645 | 1.00 | 41.79 | E | O |
| ATOM | 7691 | C | ASP | E | 416 | −34.113 | 53.333 | 45.932 | 1.00 | 26.76 | E | C |
| ATOM | 7692 | O | ASP | E | 416 | −34.832 | 54.117 | 45.320 | 1.00 | 27.85 | E | O |
| ATOM | 7693 | N | ALA | E | 417 | −32.817 | 53.544 | 46.132 | 1.00 | 25.75 | E | N |
| ATOM | 7694 | CA | ALA | E | 417 | −32.139 | 54.730 | 45.615 | 1.00 | 25.09 | E | C |
| ATOM | 7695 | CB | ALA | E | 417 | −30.855 | 54.968 | 46.387 | 1.00 | 24.35 | E | C |
| ATOM | 7696 | C | ALA | E | 417 | −31.839 | 54.547 | 44.129 | 1.00 | 24.66 | E | C |
| ATOM | 7697 | O | ALA | E | 417 | −31.579 | 55.512 | 43.406 | 1.00 | 23.70 | E | O |
| ATOM | 7698 | N | LYS | E | 418 | −31.847 | 53.289 | 43.699 | 1.00 | 23.28 | E | N |
| ATOM | 7699 | CA | LYS | E | 418 | −31.634 | 52.914 | 42.306 | 1.00 | 22.16 | E | C |
| ATOM | 7700 | CB | LYS | E | 418 | −32.702 | 53.583 | 41.432 | 1.00 | 21.86 | E | C |
| ATOM | 7701 | CG | LYS | E | 418 | −32.627 | 53.202 | 39.959 | 1.00 | 23.90 | E | C |
| ATOM | 7702 | CD | LYS | E | 418 | −33.674 | 53.945 | 39.147 | 1.00 | 26.85 | E | C |
| ATOM | 7703 | CE | LYS | E | 418 | −34.029 | 53.201 | 37.867 | 1.00 | 28.59 | E | C |
| ATOM | 7704 | NZ | LYS | E | 418 | −34.663 | 54.106 | 36.860 | 1.00 | 29.13 | E | N |
| ATOM | 7705 | C | LYS | E | 418 | −30.277 | 53.129 | 41.647 | 1.00 | 20.07 | E | C |
| ATOM | 7706 | O | LYS | E | 418 | −29.727 | 52.200 | 41.065 | 1.00 | 21.05 | E | O |
| ATOM | 7707 | N | TYR | E | 419 | −29.734 | 54.338 | 41.733 | 1.00 | 19.86 | E | N |
| ATOM | 7708 | CA | TYR | E | 419 | −28.478 | 54.645 | 41.045 | 1.00 | 19.55 | E | C |
| ATOM | 7709 | CB | TYR | E | 419 | −28.498 | 56.115 | 40.634 | 1.00 | 17.86 | E | C |
| ATOM | 7710 | CG | TYR | E | 419 | −29.744 | 56.437 | 39.846 | 1.00 | 19.53 | E | C |
| ATOM | 7711 | CD1 | TYR | E | 419 | −29.904 | 55.965 | 38.546 | 1.00 | 19.56 | E | C |
| ATOM | 7712 | CE1 | TYR | E | 419 | −31.085 | 56.175 | 37.844 | 1.00 | 19.90 | E | C |
| ATOM | 7713 | CD2 | TYR | E | 419 | −30.798 | 57.139 | 40.422 | 1.00 | 19.59 | E | C |
| ATOM | 7714 | CE2 | TYR | E | 419 | −31.985 | 57.354 | 39.726 | 1.00 | 19.16 | E | C |
| ATOM | 7715 | CZ | TYR | E | 419 | −32.121 | 56.864 | 38.438 | 1.00 | 20.25 | E | C |
| ATOM | 7716 | OH | TYR | E | 419 | −33.302 | 57.031 | 37.751 | 1.00 | 21.39 | E | O |
| ATOM | 7717 | C | TYR | E | 419 | −27.130 | 54.294 | 41.664 | 1.00 | 18.99 | E | C |
| ATOM | 7718 | O | TYR | E | 419 | −26.106 | 54.384 | 40.986 | 1.00 | 19.20 | E | O |
| ATOM | 7719 | N | GLN | E | 420 | −27.116 | 53.883 | 42.926 | 1.00 | 17.29 | E | N |
| ATOM | 7720 | CA | GLN | E | 420 | −25.860 | 53.510 | 43.573 | 1.00 | 16.80 | E | C |
| ATOM | 7721 | CB | GLN | E | 420 | −25.738 | 54.198 | 44.935 | 1.00 | 20.14 | E | C |
| ATOM | 7722 | CG | GLN | E | 420 | −25.320 | 55.655 | 44.848 | 1.00 | 23.08 | E | C |
| ATOM | 7723 | CD | GLN | E | 420 | −26.451 | 56.558 | 44.399 | 1.00 | 27.85 | E | C |
| ATOM | 7724 | OE1 | GLN | E | 420 | −26.370 | 57.211 | 43.353 | 1.00 | 29.37 | E | O |
| ATOM | 7725 | NE2 | GLN | E | 420 | −27.516 | 56.605 | 45.191 | 1.00 | 26.93 | E | N |
| ATOM | 7726 | C | GLN | E | 420 | −25.744 | 51.996 | 43.742 | 1.00 | 14.65 | E | C |
| ATOM | 7727 | O | GLN | E | 420 | −26.713 | 51.319 | 44.089 | 1.00 | 15.31 | E | O |
| ATOM | 7728 | N | HIS | E | 421 | −24.546 | 51.478 | 43.484 | 1.00 | 12.24 | E | N |
| ATOM | 7729 | CA | HIS | E | 421 | −24.252 | 50.053 | 43.598 | 1.00 | 12.61 | E | C |
| ATOM | 7730 | CB | HIS | E | 421 | −23.926 | 49.466 | 42.219 | 1.00 | 10.50 | E | C |
| ATOM | 7731 | CG | HIS | E | 421 | −25.068 | 49.524 | 41.253 | 1.00 | 11.42 | E | C |
| ATOM | 7732 | CD2 | HIS | E | 421 | −25.674 | 50.575 | 40.649 | 1.00 | 9.83 | E | C |
| ATOM | 7733 | ND1 | HIS | E | 421 | −25.752 | 48.399 | 40.841 | 1.00 | 11.16 | E | N |
| ATOM | 7734 | CE1 | HIS | E | 421 | −26.731 | 48.755 | 40.029 | 1.00 | 10.53 | E | C |
| ATOM | 7735 | NE2 | HIS | E | 421 | −26.706 | 50.070 | 39.896 | 1.00 | 10.97 | E | N |
| ATOM | 7736 | C | HIS | E | 421 | −23.046 | 49.892 | 44.519 | 1.00 | 12.59 | E | C |
| ATOM | 7737 | O | HIS | E | 421 | −22.371 | 50.872 | 44.819 | 1.00 | 14.34 | E | O |
| ATOM | 7738 | N | ALA | E | 422 | −22.767 | 48.663 | 44.951 | 1.00 | 13.57 | E | N |
| ATOM | 7739 | CA | ALA | E | 422 | −21.638 | 48.410 | 45.844 | 1.00 | 13.65 | E | C |
| ATOM | 7740 | CB | ALA | E | 422 | −22.097 | 48.524 | 47.303 | 1.00 | 12.91 | E | C |
| ATOM | 7741 | C | ALA | E | 422 | −21.000 | 47.049 | 45.609 | 1.00 | 13.43 | E | C |
| ATOM | 7742 | O | ALA | E | 422 | −21.678 | 46.104 | 45.208 | 1.00 | 14.85 | E | O |
| ATOM | 7743 | N | GLU | E | 423 | −19.696 | 46.952 | 45.872 | 1.00 | 12.69 | E | N |
| ATOM | 7744 | CA | GLU | E | 423 | −18.948 | 45.704 | 45.702 | 1.00 | 14.54 | E | C |
| ATOM | 7745 | CB | GLU | E | 423 | −17.783 | 45.906 | 44.721 | 1.00 | 13.83 | E | C |
| ATOM | 7746 | CG | GLU | E | 423 | −18.186 | 46.393 | 43.328 | 1.00 | 14.91 | E | C |
| ATOM | 7747 | CD | GLU | E | 423 | −17.034 | 46.294 | 42.338 | 1.00 | 17.73 | E | C |
| ATOM | 7748 | OE1 | GLU | E | 423 | −16.896 | 45.238 | 41.674 | 1.00 | 18.46 | E | O |
| ATOM | 7749 | OE2 | GLU | E | 423 | −16.256 | 47.269 | 42.236 | 1.00 | 18.75 | E | O |
| ATOM | 7750 | C | GLU | E | 423 | −18.399 | 45.216 | 47.051 | 1.00 | 14.79 | E | C |
| ATOM | 7751 | O | GLU | E | 423 | −17.181 | 45.184 | 47.271 | 1.00 | 16.59 | E | O |
| ATOM | 7752 | N | PRO | E | 424 | −19.293 | 44.811 | 47.968 | 1.00 | 15.63 | E | N |
| ATOM | 7753 | CD | PRO | E | 424 | −20.759 | 44.792 | 47.806 | 1.00 | 15.56 | E | C |
| ATOM | 7754 | CA | PRO | E | 424 | −18.871 | 44.333 | 49.290 | 1.00 | 14.62 | E | C |
| ATOM | 7755 | CB | PRO | E | 424 | −20.187 | 44.064 | 50.016 | 1.00 | 15.68 | E | C |
| ATOM | 7756 | CG | PRO | E | 424 | −21.218 | 43.955 | 48.938 | 1.00 | 16.54 | E | C |
| ATOM | 7757 | C | PRO | E | 424 | −17.945 | 43.122 | 49.296 | 1.00 | 15.79 | E | C |
| ATOM | 7758 | O | PRO | E | 424 | −18.160 | 42.148 | 48.581 | 1.00 | 15.27 | E | O |
| ATOM | 7759 | N | ARG | E | 425 | −16.916 | 43.197 | 50.134 | 1.00 | 16.88 | E | N |
| ATOM | 7760 | CA | ARG | E | 425 | −15.927 | 42.130 | 50.271 | 1.00 | 16.13 | E | C |
| ATOM | 7761 | CB | ARG | E | 425 | −14.524 | 42.752 | 50.415 | 1.00 | 14.53 | E | C |
| ATOM | 7762 | CG | ARG | E | 425 | −13.621 | 42.563 | 49.201 | 1.00 | 15.51 | E | C |
| ATOM | 7763 | CD | ARG | E | 425 | −13.067 | 43.870 | 48.636 | 1.00 | 15.66 | E | C |
| ATOM | 7764 | NE | ARG | E | 425 | −14.083 | 44.632 | 47.918 | 1.00 | 16.51 | E | N |
| ATOM | 7765 | CZ | ARG | E | 425 | −13.844 | 45.520 | 46.951 | 1.00 | 14.08 | E | C |
| ATOM | 7766 | NH1 | ARG | E | 425 | −12.611 | 45.790 | 46.544 | 1.00 | 11.20 | E | N |
| ATOM | 7767 | NH2 | ARG | E | 425 | −14.859 | 46.165 | 46.400 | 1.00 | 13.10 | E | N |
| ATOM | 7768 | C | ARG | E | 425 | −16.244 | 41.227 | 51.478 | 1.00 | 16.75 | E | C |
| ATOM | 7769 | O | ARG | E | 425 | −16.449 | 41.714 | 52.588 | 1.00 | 16.20 | E | O |
| ATOM | 7770 | N | LEU | E | 426 | −16.300 | 39.916 | 51.237 | 1.00 | 17.26 | E | N |
| ATOM | 7771 | CA | LEU | E | 426 | −16.568 | 38.919 | 52.272 | 1.00 | 16.28 | E | C |
| ATOM | 7772 | CB | LEU | E | 426 | −17.571 | 37.866 | 51.779 | 1.00 | 15.41 | E | C |
| ATOM | 7773 | CG | LEU | E | 426 | −19.026 | 38.284 | 51.576 | 1.00 | 15.33 | E | C |
| ATOM | 7774 | CD1 | LEU | E | 426 | −19.788 | 37.172 | 50.855 | 1.00 | 13.88 | E | C |
| ATOM | 7775 | CD2 | LEU | E | 426 | −19.657 | 38.582 | 52.930 | 1.00 | 13.36 | E | C |
| ATOM | 7776 | C | LEU | E | 426 | −15.238 | 38.245 | 52.580 | 1.00 | 16.65 | E | C |
| ATOM | 7777 | O | LEU | E | 426 | −14.356 | 38.208 | 51.727 | 1.00 | 16.79 | E | O |
| ATOM | 7778 | N | SER | E | 427 | −15.100 | 37.696 | 53.786 | 1.00 | 16.47 | E | N |
| ATOM | 7779 | CA | SER | E | 427 | −13.843 | 37.070 | 54.192 | 1.00 | 17.18 | E | C |
| ATOM | 7780 | CB | SER | E | 427 | −13.488 | 37.483 | 55.629 | 1.00 | 16.66 | E | C |
| ATOM | 7781 | OG | SER | E | 427 | −13.398 | 38.888 | 55.761 | 1.00 | 18.30 | E | O |
| ATOM | 7782 | C | SER | E | 427 | −13.727 | 35.562 | 54.110 | 1.00 | 15.95 | E | C |
| ATOM | 7783 | O | SER | E | 427 | −14.651 | 34.836 | 54.456 | 1.00 | 18.31 | E | O |
| ATOM | 7784 | N | ILE | E | 428 | −12.561 | 35.118 | 53.651 | 1.00 | 16.49 | E | N |
| ATOM | 7785 | CA | ILE | E | 428 | −12.196 | 33.708 | 53.562 | 1.00 | 17.80 | E | C |
| ATOM | 7786 | CB | ILE | E | 428 | −12.196 | 33.185 | 52.106 | 1.00 | 16.65 | E | C |
| ATOM | 7787 | CG2 | ILE | E | 428 | −11.353 | 31.916 | 51.997 | 1.00 | 15.60 | E | C |
| ATOM | 7788 | CG1 | ILE | E | 428 | −13.633 | 32.891 | 51.663 | 1.00 | 15.61 | E | C |
| ATOM | 7789 | CD1 | ILE | E | 428 | −14.273 | 31.659 | 52.313 | 1.00 | 13.46 | E | C |
| ATOM | 7790 | C | ILE | E | 428 | −10.774 | 33.797 | 54.094 | 1.00 | 18.74 | E | C |
| ATOM | 7791 | O | ILE | E | 428 | −9.940 | 34.469 | 53.496 | 1.00 | 20.20 | E | O |
| ATOM | 7792 | N | TYR | E | 429 | −10.503 | 33.140 | 55.220 | 1.00 | 21.26 | E | N |
| ATOM | 7793 | CA | TYR | E | 429 | −9.187 | 33.222 | 55.869 | 1.00 | 22.89 | E | C |
| ATOM | 7794 | CB | TYR | E | 429 | −9.354 | 33.229 | 57.391 | 1.00 | 21.85 | E | C |
| ATOM | 7795 | CG | TYR | E | 429 | −10.382 | 34.215 | 57.893 | 1.00 | 21.00 | E | C |
| ATOM | 7796 | CD1 | TYR | E | 429 | −11.730 | 33.871 | 57.958 | 1.00 | 21.71 | E | C |
| ATOM | 7797 | CE1 | TYR | E | 429 | −12.679 | 34.778 | 58.408 | 1.00 | 20.28 | E | C |
| ATOM | 7798 | CD2 | TYR | E | 429 | −10.008 | 35.494 | 58.295 | 1.00 | 19.38 | E | C |
| ATOM | 7799 | CE2 | TYR | E | 429 | −10.947 | 36.407 | 58.746 | 1.00 | 20.13 | E | C |
| ATOM | 7800 | CZ | TYR | E | 429 | −12.280 | 36.042 | 58.801 | 1.00 | 21.25 | E | C |
| ATOM | 7801 | OH | TYR | E | 429 | −13.213 | 36.945 | 59.256 | 1.00 | 22.96 | E | O |
| ATOM | 7802 | C | TYR | E | 429 | −8.122 | 32.200 | 55.540 | 1.00 | 23.93 | E | C |
| ATOM | 7803 | O | TYR | E | 429 | −6.936 | 32.473 | 55.727 | 1.00 | 25.07 | E | O |
| ATOM | 7804 | N | GLY | E | 430 | −8.522 | 31.024 | 55.075 | 1.00 | 24.46 | E | N |
| ATOM | 7805 | CA | GLY | E | 430 | −7.532 | 30.005 | 54.779 | 1.00 | 25.33 | E | C |
| ATOM | 7806 | C | GLY | E | 430 | −7.115 | 29.349 | 56.084 | 1.00 | 25.93 | E | C |
| ATOM | 7807 | O | GLY | E | 430 | −6.045 | 28.745 | 56.187 | 1.00 | 26.64 | E | O |
| ATOM | 7808 | N | ARG | E | 431 | −7.971 | 29.485 | 57.090 | 1.00 | 26.37 | E | N |
| ATOM | 7809 | CA | ARG | E | 431 | −7.727 | 28.906 | 58.404 | 1.00 | 28.37 | E | C |
| ATOM | 7810 | CB | ARG | E | 431 | −8.455 | 29.721 | 59.475 | 1.00 | 30.05 | E | C |
| ATOM | 7811 | CG | ARG | E | 431 | −8.194 | 29.271 | 60.910 | 1.00 | 34.27 | E | C |
| ATOM | 7812 | CD | ARG | E | 431 | −9.300 | 29.748 | 61.845 | 1.00 | 37.66 | E | C |
| ATOM | 7813 | NE | ARG | E | 431 | −10.617 | 29.296 | 61.395 | 1.00 | 42.62 | E | N |
| ATOM | 7814 | CZ | ARG | E | 431 | −11.586 | 30.102 | 60.963 | 1.00 | 43.49 | E | C |
| ATOM | 7815 | NH1 | ARG | E | 431 | −11.393 | 31.418 | 60.921 | 1.00 | 43.78 | E | N |
| ATOM | 7816 | NH2 | ARG | E | 431 | −12.749 | 29.591 | 60.574 | 1.00 | 43.62 | E | N |
| ATOM | 7817 | C | ARG | E | 431 | −8.250 | 27.477 | 58.394 | 1.00 | 29.16 | E | C |
| ATOM | 7818 | O | ARG | E | 431 | −7.662 | 26.584 | 58.996 | 1.00 | 28.79 | E | O |
| ATOM | 7819 | N | SER | E | 432 | −9.362 | 27.269 | 57.696 | 1.00 | 30.88 | E | N |
| ATOM | 7820 | CA | SER | E | 432 | −9.972 | 25.950 | 57.590 | 1.00 | 32.58 | E | C |
| ATOM | 7821 | CB | SER | E | 432 | −11.125 | 25.820 | 58.587 | 1.00 | 32.73 | E | C |
| ATOM | 7822 | OG | SER | E | 432 | −11.921 | 24.690 | 58.275 | 1.00 | 33.63 | E | O |
| ATOM | 7823 | C | SER | E | 432 | −10.494 | 25.718 | 56.172 | 1.00 | 34.46 | E | C |
| ATOM | 7824 | O | SER | E | 432 | −10.953 | 26.651 | 55.510 | 1.00 | 35.23 | E | O |
| ATOM | 7825 | N | PRO | E | 433 | −10.445 | 24.462 | 55.694 | 1.00 | 34.21 | E | N |
| ATOM | 7826 | CD | PRO | E | 433 | −9.939 | 23.281 | 56.414 | 1.00 | 33.94 | E | C |
| ATOM | 7827 | CA | PRO | E | 433 | −10.914 | 24.119 | 54.344 | 1.00 | 34.25 | E | C |
| ATOM | 7828 | CB | PRO | E | 433 | −10.328 | 22.733 | 54.106 | 1.00 | 34.36 | E | C |
| ATOM | 7829 | CG | PRO | E | 433 | −10.237 | 22.141 | 55.468 | 1.00 | 34.39 | E | C |
| ATOM | 7830 | C | PRO | E | 433 | −12.430 | 24.134 | 54.164 | 1.00 | 33.31 | E | C |
| ATOM | 7831 | O | PRO | E | 433 | −12.926 | 24.168 | 53.032 | 1.00 | 33.30 | E | O |
| ATOM | 7832 | N | ASP | E | 434 | −13.166 | 24.113 | 55.271 | 1.00 | 31.56 | E | N |
| ATOM | 7833 | CA | ASP | E | 434 | −14.624 | 24.122 | 55.196 | 1.00 | 29.98 | E | C |
| ATOM | 7834 | CB | ASP | E | 434 | −15.210 | 23.306 | 56.357 | 1.00 | 33.65 | E | C |
| ATOM | 7835 | CG | ASP | E | 434 | −15.237 | 24.076 | 57.667 | 1.00 | 37.91 | E | C |
| ATOM | 7836 | OD1 | ASP | E | 434 | −14.405 | 24.990 | 57.854 | 1.00 | 41.02 | E | O |
| ATOM | 7837 | OD2 | ASP | E | 434 | −16.098 | 23.763 | 58.516 | 1.00 | 40.78 | E | O |
| ATOM | 7838 | C | ASP | E | 434 | −15.230 | 25.533 | 55.173 | 1.00 | 27.37 | E | C |
| ATOM | 7839 | O | ASP | E | 434 | −16.451 | 25.689 | 55.172 | 1.00 | 25.83 | E | O |
| ATOM | 7840 | N | GLU | E | 435 | −14.377 | 26.554 | 55.137 | 1.00 | 24.40 | E | N |
| ATOM | 7841 | CA | GLU | E | 435 | −14.842 | 27.939 | 55.120 | 1.00 | 24.19 | E | C |
| ATOM | 7842 | CB | GLU | E | 435 | −13.643 | 28.886 | 55.159 | 1.00 | 24.56 | E | C |
| ATOM | 7843 | CG | GLU | E | 435 | −12.882 | 28.848 | 56.471 | 1.00 | 24.88 | E | C |
| ATOM | 7844 | CD | GLU | E | 435 | −11.896 | 29.987 | 56.604 | 1.00 | 24.93 | E | C |
| ATOM | 7845 | OE1 | GLU | E | 435 | −10.729 | 29.714 | 56.946 | 1.00 | 24.40 | E | O |
| ATOM | 7846 | OE2 | GLU | E | 435 | −12.290 | 31.152 | 56.369 | 1.00 | 26.42 | E | O |
| ATOM | 7847 | C | GLU | E | 435 | −15.705 | 28.254 | 53.900 | 1.00 | 22.83 | E | C |
| ATOM | 7848 | O | GLU | E | 435 | −16.735 | 28.932 | 54.003 | 1.00 | 22.60 | E | O |
| ATOM | 7849 | N | TRP | E | 436 | −15.277 | 27.758 | 52.742 | 1.00 | 22.32 | E | N |
| ATOM | 7850 | CA | TRP | E | 436 | −16.006 | 27.978 | 51.498 | 1.00 | 21.24 | E | C |
| ATOM | 7851 | CB | TRP | E | 436 | −15.209 | 27.409 | 50.318 | 1.00 | 18.90 | E | C |
| ATOM | 7852 | CG | TRP | E | 436 | −14.106 | 28.322 | 49.835 | 1.00 | 15.97 | E | C |
| ATOM | 7853 | CD2 | TRP | E | 436 | −14.261 | 29.515 | 49.055 | 1.00 | 15.22 | E | C |
| ATOM | 7854 | CE2 | TRP | E | 436 | −12.965 | 30.028 | 48.808 | 1.00 | 14.70 | E | C |
| ATOM | 7855 | CE3 | TRP | E | 436 | −15.369 | 30.199 | 48.539 | 1.00 | 15.75 | E | C |
| ATOM | 7856 | CD1 | TRP | E | 436 | −12.763 | 28.166 | 50.027 | 1.00 | 17.18 | E | C |
| ATOM | 7857 | NE1 | TRP | E | 436 | −12.068 | 29.188 | 49.412 | 1.00 | 14.44 | E | N |
| ATOM | 7858 | CZ2 | TRP | E | 436 | −12.748 | 31.194 | 48.066 | 1.00 | 15.52 | E | C |
| ATOM | 7859 | CZ3 | TRP | E | 436 | −15.154 | 31.360 | 47.798 | 1.00 | 16.08 | E | C |
| ATOM | 7860 | CH2 | TRP | E | 436 | −13.850 | 31.846 | 47.569 | 1.00 | 15.01 | E | C |
| ATOM | 7861 | C | TRP | E | 436 | −17.378 | 27.312 | 51.589 | 1.00 | 21.25 | E | C |
| ATOM | 7862 | O | TRP | E | 436 | −18.401 | 27.894 | 51.216 | 1.00 | 20.48 | E | O |
| ATOM | 7863 | N | SER | E | 437 | −17.396 | 26.088 | 52.101 | 1.00 | 21.78 | E | N |
| ATOM | 7864 | CA | SER | E | 437 | −18.644 | 25.358 | 52.248 | 1.00 | 22.50 | E | C |
| ATOM | 7865 | CB | SER | E | 437 | −18.385 | 23.976 | 52.833 | 1.00 | 22.38 | E | C |
| ATOM | 7866 | OG | SER | E | 437 | −19.591 | 23.436 | 53.338 | 1.00 | 26.68 | E | O |
| ATOM | 7867 | C | SER | E | 437 | −19.607 | 26.100 | 53.158 | 1.00 | 22.17 | E | C |
| ATOM | 7868 | O | SER | E | 437 | −20.808 | 26.160 | 52.888 | 1.00 | 24.15 | E | O |
| ATOM | 7869 | N | LYS | E | 438 | −19.076 | 26.660 | 54.240 | 1.00 | 21.62 | E | N |
| ATOM | 7870 | CA | LYS | E | 438 | −19.894 | 27.395 | 55.199 | 1.00 | 22.49 | E | C |
| ATOM | 7871 | CB | LYS | E | 438 | −19.093 | 27.663 | 56.479 | 1.00 | 23.37 | E | C |
| ATOM | 7872 | CG | LYS | E | 438 | −18.716 | 26.419 | 57.260 | 1.00 | 24.95 | E | C |
| ATOM | 7873 | CD | LYS | E | 438 | −18.983 | 26.619 | 58.739 | 1.00 | 28.85 | E | C |
| ATOM | 7874 | CE | LYS | E | 438 | −17.890 | 26.007 | 59.596 | 1.00 | 32.81 | E | C |
| ATOM | 7875 | NZ | LYS | E | 438 | −18.207 | 26.123 | 61.050 | 1.00 | 34.72 | E | N |
| ATOM | 7876 | C | LYS | E | 438 | −20.398 | 28.718 | 54.638 | 1.00 | 20.63 | E | C |
| ATOM | 7877 | O | LYS | E | 438 | −21.572 | 29.056 | 54.789 | 1.00 | 20.39 | E | O |
| ATOM | 7878 | N | LEU | E | 439 | −19.504 | 29.466 | 53.995 | 1.00 | 18.98 | E | N |
| ATOM | 7879 | CA | LEU | E | 439 | −19.863 | 30.765 | 53.437 | 1.00 | 17.63 | E | C |
| ATOM | 7880 | CB | LEU | E | 439 | −18.604 | 31.490 | 52.946 | 1.00 | 16.78 | E | C |
| ATOM | 7881 | CG | LEU | E | 439 | −18.775 | 32.942 | 52.483 | 1.00 | 16.76 | E | C |
| ATOM | 7882 | CD1 | LEU | E | 439 | −19.588 | 33.739 | 53.495 | 1.00 | 16.94 | E | C |
| ATOM | 7883 | CD2 | LEU | E | 439 | −17.403 | 33.566 | 52.288 | 1.00 | 17.46 | E | C |
| ATOM | 7884 | C | LEU | E | 439 | −20.870 | 30.642 | 52.304 | 1.00 | 18.26 | E | C |
| ATOM | 7885 | O | LEU | E | 439 | −21.833 | 31.403 | 52.236 | 1.00 | 18.60 | E | O |
| ATOM | 7886 | N | SER | E | 440 | −20.652 | 29.678 | 51.414 | 1.00 | 19.12 | E | N |
| ATOM | 7887 | CA | SER | E | 440 | −21.560 | 29.489 | 50.287 | 1.00 | 21.10 | E | C |
| ATOM | 7888 | CB | SER | E | 440 | −21.051 | 28.378 | 49.354 | 1.00 | 19.46 | E | C |
| ATOM | 7889 | OG | SER | E | 440 | −21.006 | 27.116 | 49.991 | 1.00 | 21.82 | E | O |
| ATOM | 7890 | C | SER | E | 440 | −22.959 | 29.171 | 50.787 | 1.00 | 21.09 | E | C |
| ATOM | 7891 | O | SER | E | 440 | −23.941 | 29.678 | 50.246 | 1.00 | 22.15 | E | O |
| ATOM | 7892 | N | SER | E | 441 | −23.048 | 28.346 | 51.829 | 1.00 | 22.09 | E | N |
| ATOM | 7893 | CA | SER | E | 441 | −24.339 | 27.980 | 52.417 | 1.00 | 21.89 | E | C |
| ATOM | 7894 | CB | SER | E | 441 | −24.155 | 26.885 | 53.477 | 1.00 | 22.90 | E | C |
| ATOM | 7895 | OG | SER | E | 441 | −23.542 | 25.728 | 52.929 | 1.00 | 26.47 | E | O |
| ATOM | 7896 | C | SER | E | 441 | −24.991 | 29.206 | 53.063 | 1.00 | 21.02 | E | C |
| ATOM | 7897 | O | SER | E | 441 | −26.209 | 29.394 | 52.988 | 1.00 | 21.47 | E | O |
| ATOM | 7898 | N | TRP | E | 442 | −24.175 | 30.036 | 53.706 | 1.00 | 20.15 | E | N |
| ATOM | 7899 | CA | TRP | E | 442 | −24.676 | 31.246 | 54.347 | 1.00 | 20.05 | E | C |
| ATOM | 7900 | CB | TRP | E | 442 | −23.522 | 31.976 | 55.054 | 1.00 | 20.56 | E | C |
| ATOM | 7901 | CG | TRP | E | 442 | −23.874 | 33.350 | 55.585 | 1.00 | 22.55 | E | C |
| ATOM | 7902 | CD2 | TRP | E | 442 | −23.602 | 34.616 | 54.957 | 1.00 | 24.13 | E | C |
| ATOM | 7903 | CE2 | TRP | E | 442 | −24.122 | 35.626 | 55.804 | 1.00 | 22.91 | E | C |
| ATOM | 7904 | CE3 | TRP | E | 442 | −22.973 | 34.994 | 53.758 | 1.00 | 23.44 | E | C |
| ATOM | 7905 | CD1 | TRP | E | 442 | −24.523 | 33.638 | 56.754 | 1.00 | 22.35 | E | C |
| ATOM | 7906 | NE1 | TRP | E | 442 | −24.676 | 35.003 | 56.891 | 1.00 | 23.68 | E | N |
| ATOM | 7907 | CZ2 | TRP | E | 442 | −24.030 | 36.990 | 55.495 | 1.00 | 22.63 | E | C |
| ATOM | 7908 | CZ3 | TRP | E | 442 | −22.882 | 36.356 | 53.449 | 1.00 | 24.34 | E | C |
| ATOM | 7909 | CH2 | TRP | E | 442 | −23.410 | 37.336 | 54.316 | 1.00 | 22.42 | E | C |
| ATOM | 7910 | C | TRP | E | 442 | −25.293 | 32.145 | 53.279 | 1.00 | 19.67 | E | C |
| ATOM | 7911 | O | TRP | E | 442 | −26.407 | 32.641 | 53.429 | 1.00 | 18.68 | E | O |
| ATOM | 7912 | N | PHE | E | 443 | −24.555 | 32.333 | 52.190 | 1.00 | 21.60 | E | N |
| ATOM | 7913 | CA | PHE | E | 443 | −24.992 | 33.173 | 51.079 | 1.00 | 22.21 | E | C |
| ATOM | 7914 | CB | PHE | E | 443 | −23.850 | 33.298 | 50.063 | 1.00 | 23.43 | E | C |
| ATOM | 7915 | CG | PHE | E | 443 | −24.046 | 34.395 | 49.055 | 1.00 | 24.36 | E | C |
| ATOM | 7916 | CD1 | PHE | E | 443 | −24.773 | 34.168 | 47.888 | 1.00 | 25.90 | E | C |
| ATOM | 7917 | CD2 | PHE | E | 443 | −23.496 | 35.651 | 49.264 | 1.00 | 24.24 | E | C |
| ATOM | 7918 | CE1 | PHE | E | 443 | −24.946 | 35.181 | 46.944 | 1.00 | 24.92 | E | C |
| ATOM | 7919 | CE2 | PHE | E | 443 | −23.665 | 36.667 | 48.325 | 1.00 | 24.18 | E | C |
| ATOM | 7920 | CZ | PHE | E | 443 | −24.390 | 36.431 | 47.167 | 1.00 | 24.52 | E | C |
| ATOM | 7921 | C | PHE | E | 443 | −26.254 | 32.653 | 50.387 | 1.00 | 22.21 | E | C |
| ATOM | 7922 | O | PHE | E | 443 | −27.227 | 33.397 | 50.194 | 1.00 | 22.07 | E | O |
| ATOM | 7923 | N | VAL | E | 444 | −26.235 | 31.374 | 50.020 | 1.00 | 21.83 | E | N |
| ATOM | 7924 | CA | VAL | E | 444 | −27.361 | 30.755 | 49.329 | 1.00 | 22.82 | E | C |
| ATOM | 7925 | CB | VAL | E | 444 | −26.973 | 29.364 | 48.794 | 1.00 | 23.84 | E | C |
| ATOM | 7926 | CG1 | VAL | E | 444 | −28.155 | 28.738 | 48.073 | 1.00 | 23.95 | E | C |
| ATOM | 7927 | CG2 | VAL | E | 444 | −25.783 | 29.481 | 47.856 | 1.00 | 22.75 | E | C |
| ATOM | 7928 | C | VAL | E | 444 | −28.605 | 30.609 | 50.195 | 1.00 | 24.10 | E | C |
| ATOM | 7929 | O | VAL | E | 444 | −29.686 | 31.066 | 49.827 | 1.00 | 22.51 | E | O |
| ATOM | 7930 | N | ARG | E | 445 | −28.451 | 29.966 | 51.348 | 1.00 | 25.57 | E | N |
| ATOM | 7931 | CA | ARG | E | 445 | −29.575 | 29.758 | 52.254 | 1.00 | 26.40 | E | C |
| ATOM | 7932 | CB | ARG | E | 445 | −29.115 | 28.946 | 53.462 | 1.00 | 28.34 | E | C |
| ATOM | 7933 | CG | ARG | E | 445 | −29.207 | 27.446 | 53.252 | 1.00 | 32.85 | E | C |
| ATOM | 7934 | CD | ARG | E | 445 | −28.029 | 26.716 | 53.873 | 1.00 | 37.34 | E | C |
| ATOM | 7935 | NE | ARG | E | 445 | −27.857 | 25.380 | 53.312 | 1.00 | 40.19 | E | N |
| ATOM | 7936 | CZ | ARG | E | 445 | −27.472 | 24.321 | 54.013 | 1.00 | 43.26 | E | C |
| ATOM | 7937 | NH1 | ARG | E | 445 | −27.215 | 24.435 | 55.307 | 1.00 | 44.45 | E | N |
| ATOM | 7938 | NH2 | ARG | E | 445 | −27.353 | 23.144 | 53.420 | 1.00 | 45.98 | E | N |
| ATOM | 7939 | C | ARG | E | 445 | −30.253 | 31.049 | 52.719 | 1.00 | 25.51 | E | C |
| ATOM | 7940 | O | ARG | E | 445 | −31.457 | 31.071 | 52.963 | 1.00 | 24.80 | E | O |
| ATOM | 7941 | N | ASN | E | 446 | −29.490 | 32.130 | 52.840 | 1.00 | 25.25 | E | N |
| ATOM | 7942 | CA | ASN | E | 446 | −30.074 | 33.391 | 53.278 | 1.00 | 24.91 | E | C |
| ATOM | 7943 | CB | ASN | E | 446 | −29.056 | 34.189 | 54.094 | 1.00 | 25.75 | E | C |
| ATOM | 7944 | CG | ASN | E | 446 | −28.942 | 33.691 | 55.526 | 1.00 | 25.08 | E | C |
| ATOM | 7945 | OD1 | ASN | E | 446 | −27.976 | 33.019 | 55.889 | 1.00 | 23.98 | E | O |
| ATOM | 7946 | ND2 | ASN | E | 446 | −29.934 | 34.016 | 56.345 | 1.00 | 25.64 | E | N |
| ATOM | 7947 | C | ASN | E | 446 | −30.551 | 34.215 | 52.092 | 1.00 | 25.27 | E | C |
| ATOM | 7948 | O | ASN | E | 446 | −31.040 | 35.336 | 52.258 | 1.00 | 22.98 | E | O |
| ATOM | 7949 | N | ARG | E | 447 | −30.411 | 33.646 | 50.897 | 1.00 | 26.84 | E | N |
| ATOM | 7950 | CA | ARG | E | 447 | −30.821 | 34.307 | 49.663 | 1.00 | 28.40 | E | C |
| ATOM | 7951 | CB | ARG | E | 447 | −32.349 | 34.356 | 49.550 | 1.00 | 29.42 | E | C |
| ATOM | 7952 | CG | ARG | E | 447 | −33.054 | 33.103 | 50.047 | 1.00 | 35.61 | E | C |
| ATOM | 7953 | CD | ARG | E | 447 | −33.372 | 32.135 | 48.913 | 1.00 | 40.23 | E | C |
| ATOM | 7954 | NE | ARG | E | 447 | −34.242 | 32.743 | 47.907 | 1.00 | 43.90 | E | N |
| ATOM | 7955 | CZ | ARG | E | 447 | −34.333 | 32.326 | 46.648 | 1.00 | 44.37 | E | C |
| ATOM | 7956 | NH1 | ARG | E | 447 | −33.609 | 31.294 | 46.232 | 1.00 | 45.84 | E | N |
| ATOM | 7957 | NH2 | ARG | E | 447 | −35.145 | 32.945 | 45.802 | 1.00 | 46.18 | E | N |
| ATOM | 7958 | C | ARG | E | 447 | −30.264 | 35.716 | 49.619 | 1.00 | 28.49 | E | C |
| ATOM | 7959 | O | ARG | E | 447 | −31.004 | 36.685 | 49.441 | 1.00 | 28.66 | E | O |
| ATOM | 7960 | N | ILE | E | 448 | −28.956 | 35.833 | 49.798 | 1.00 | 29.01 | E | N |
| ATOM | 7961 | CA | ILE | E | 448 | −28.319 | 37.139 | 49.765 | 1.00 | 30.24 | E | C |
| ATOM | 7962 | CB | ILE | E | 448 | −27.001 | 37.136 | 50.570 | 1.00 | 29.64 | E | C |
| ATOM | 7963 | CG2 | ILE | E | 448 | −26.172 | 38.359 | 50.241 | 1.00 | 29.70 | E | C |
| ATOM | 7964 | CG1 | ILE | E | 448 | −27.309 | 37.122 | 52.065 | 1.00 | 28.82 | E | C |
| ATOM | 7965 | CD1 | ILE | E | 448 | −26.318 | 36.334 | 52.848 | 1.00 | 29.55 | E | C |
| ATOM | 7966 | C | ILE | E | 448 | −28.036 | 37.482 | 48.307 | 1.00 | 30.69 | E | C |
| ATOM | 7967 | O | ILE | E | 448 | −27.099 | 36.966 | 47.704 | 1.00 | 32.98 | E | O |
| ATOM | 7968 | N | TYR | E | 449 | −28.875 | 38.331 | 47.735 | 1.00 | 29.09 | E | N |
| ATOM | 7969 | CA | TYR | E | 449 | −28.708 | 38.741 | 46.355 | 1.00 | 27.59 | E | C |
| ATOM | 7970 | CB | TYR | E | 449 | −29.235 | 37.669 | 45.388 | 1.00 | 28.37 | E | C |
| ATOM | 7971 | CG | TYR | E | 449 | −29.465 | 38.225 | 44.002 | 1.00 | 29.61 | E | C |
| ATOM | 7972 | CD1 | TYR | E | 449 | −28.427 | 38.282 | 43.072 | 1.00 | 31.11 | E | C |
| ATOM | 7973 | CE1 | TYR | E | 449 | −28.598 | 38.910 | 41.839 | 1.00 | 32.40 | E | C |
| ATOM | 7974 | CD2 | TYR | E | 449 | −30.685 | 38.801 | 43.659 | 1.00 | 30.07 | E | C |
| ATOM | 7975 | CE2 | TYR | E | 449 | −30.867 | 39.430 | 42.433 | 1.00 | 32.26 | E | C |
| ATOM | 7976 | CZ | TYR | E | 449 | −29.820 | 39.485 | 41.530 | 1.00 | 32.63 | E | C |
| ATOM | 7977 | OH | TYR | E | 449 | −29.995 | 40.135 | 40.331 | 1.00 | 36.25 | E | O |
| ATOM | 7978 | C | TYR | E | 449 | −29.479 | 40.032 | 46.155 | 1.00 | 26.42 | E | C |
| ATOM | 7979 | O | TYR | E | 449 | −30.682 | 40.087 | 46.395 | 1.00 | 27.92 | E | O |
| ATOM | 7980 | N | SER | E | 450 | −28.782 | 41.074 | 45.727 | 1.00 | 24.49 | E | N |
| ATOM | 7981 | CA | SER | E | 450 | −29.416 | 42.363 | 45.484 | 1.00 | 24.35 | E | C |
| ATOM | 7982 | CB | SER | E | 450 | −28.905 | 43.416 | 46.477 | 1.00 | 23.75 | E | C |
| ATOM | 7983 | OG | SER | E | 450 | −29.212 | 44.735 | 46.046 | 1.00 | 26.23 | E | O |
| ATOM | 7984 | C | SER | E | 450 | −29.046 | 42.762 | 44.066 | 1.00 | 23.54 | E | C |
| ATOM | 7985 | O | SER | E | 450 | −27.949 | 42.456 | 43.594 | 1.00 | 23.94 | E | O |
| ATOM | 7986 | N | SER | E | 451 | −29.963 | 43.427 | 43.381 | 1.00 | 21.87 | E | N |
| ATOM | 7987 | CA | SER | E | 451 | −29.687 | 43.843 | 42.024 | 1.00 | 23.93 | E | C |
| ATOM | 7988 | CB | SER | E | 451 | −30.976 | 44.274 | 41.344 | 1.00 | 22.19 | E | C |
| ATOM | 7989 | OG | SER | E | 451 | −31.463 | 45.442 | 41.963 | 1.00 | 27.69 | E | O |
| ATOM | 7990 | C | SER | E | 451 | −28.685 | 44.995 | 42.032 | 1.00 | 23.61 | E | C |
| ATOM | 7991 | O | SER | E | 451 | −28.174 | 45.383 | 40.982 | 1.00 | 27.00 | E | O |
| ATOM | 7992 | N | ASN | E | 452 | −28.397 | 45.535 | 43.215 | 1.00 | 20.72 | E | N |
| ATOM | 7993 | CA | ASN | E | 452 | −27.448 | 46.639 | 43.334 | 1.00 | 17.97 | E | C |
| ATOM | 7994 | CB | ASN | E | 452 | −28.103 | 47.844 | 44.001 | 1.00 | 16.34 | E | C |
| ATOM | 7995 | CG | ASN | E | 452 | −28.994 | 48.614 | 43.057 | 1.00 | 16.61 | E | C |
| ATOM | 7996 | OD1 | ASN | E | 452 | −29.938 | 48.061 | 42.498 | 1.00 | 16.20 | E | O |
| ATOM | 7997 | ND2 | ASN | E | 452 | −28.705 | 49.903 | 42.877 | 1.00 | 12.48 | E | N |
| ATOM | 7998 | C | ASN | E | 452 | −26.185 | 46.273 | 44.104 | 1.00 | 17.28 | E | C |
| ATOM | 7999 | O | ASN | E | 452 | −25.506 | 47.158 | 44.627 | 1.00 | 17.49 | E | O |
| ATOM | 8000 | N | MET | E | 453 | −25.869 | 44.978 | 44.157 | 1.00 | 16.98 | E | N |
| ATOM | 8001 | CA | MET | E | 453 | −24.680 | 44.493 | 44.854 | 1.00 | 15.55 | E | C |
| ATOM | 8002 | CB | MET | E | 453 | −25.046 | 44.017 | 46.260 | 1.00 | 16.23 | E | C |
| ATOM | 8003 | CG | MET | E | 453 | −25.121 | 45.096 | 47.311 | 1.00 | 16.98 | E | C |
| ATOM | 8004 | SD | MET | E | 453 | −25.460 | 44.388 | 48.945 | 1.00 | 22.07 | E | S |
| ATOM | 8005 | CE | MET | E | 453 | −25.061 | 45.793 | 49.967 | 1.00 | 19.45 | E | C |
| ATOM | 8006 | C | MET | E | 453 | −24.007 | 43.326 | 44.141 | 1.00 | 15.16 | E | C |
| ATOM | 8007 | O | MET | E | 453 | −24.682 | 42.404 | 43.711 | 1.00 | 15.89 | E | O |
| ATOM | 8008 | N | THR | E | 454 | −22.681 | 43.376 | 44.007 | 1.00 | 14.53 | E | N |
| ATOM | 8009 | CA | THR | E | 454 | −21.916 | 42.273 | 43.417 | 1.00 | 14.22 | E | C |
| ATOM | 8010 | CB | THR | E | 454 | −21.216 | 42.651 | 42.063 | 1.00 | 13.38 | E | C |
| ATOM | 8011 | OG1 | THR | E | 454 | −20.454 | 43.855 | 42.199 | 1.00 | 12.85 | E | O |
| ATOM | 8012 | CG2 | THR | E | 454 | −22.264 | 42.835 | 40.977 | 1.00 | 12.00 | E | C |
| ATOM | 8013 | C | THR | E | 454 | −20.899 | 41.920 | 44.502 | 1.00 | 14.08 | E | C |
| ATOM | 8014 | O | THR | E | 454 | −20.553 | 42.774 | 45.318 | 1.00 | 16.05 | E | O |
| ATOM | 8015 | N | TRP | E | 455 | −20.415 | 40.683 | 44.519 | 1.00 | 15.55 | E | N |
| ATOM | 8016 | CA | TRP | E | 455 | −19.516 | 40.253 | 45.583 | 1.00 | 15.29 | E | C |
| ATOM | 8017 | CB | TRP | E | 455 | −20.203 | 39.120 | 46.364 | 1.00 | 16.31 | E | C |
| ATOM | 8018 | CG | TRP | E | 455 | −21.542 | 39.532 | 46.896 | 1.00 | 15.50 | E | C |
| ATOM | 8019 | CD2 | TRP | E | 455 | −21.817 | 40.079 | 48.192 | 1.00 | 15.59 | E | C |
| ATOM | 8020 | CE2 | TRP | E | 455 | −23.185 | 40.426 | 48.219 | 1.00 | 15.39 | E | C |
| ATOM | 8021 | CE3 | TRP | E | 455 | −21.036 | 40.314 | 49.331 | 1.00 | 15.43 | E | C |
| ATOM | 8022 | CD1 | TRP | E | 455 | −22.724 | 39.559 | 46.212 | 1.00 | 14.38 | E | C |
| ATOM | 8023 | NE1 | TRP | E | 455 | −23.716 | 40.098 | 46.999 | 1.00 | 16.89 | E | N |
| ATOM | 8024 | CZ2 | TRP | E | 455 | −23.790 | 40.997 | 49.342 | 1.00 | 16.04 | E | C |
| ATOM | 8025 | CZ3 | TRP | E | 455 | −21.641 | 40.880 | 50.449 | 1.00 | 17.12 | E | C |
| ATOM | 8026 | CH2 | TRP | E | 455 | −23.004 | 41.217 | 50.443 | 1.00 | 16.00 | E | C |
| ATOM | 8027 | C | TRP | E | 455 | −18.092 | 39.834 | 45.246 | 1.00 | 17.00 | E | C |
| ATOM | 8028 | O | TRP | E | 455 | −17.819 | 39.309 | 44.174 | 1.00 | 15.67 | E | O |
| ATOM | 8029 | N | MET | E | 456 | −17.194 | 40.069 | 46.202 | 1.00 | 16.71 | E | N |
| ATOM | 8030 | CA | MET | E | 456 | −15.786 | 39.709 | 46.078 | 1.00 | 16.73 | E | C |
| ATOM | 8031 | CB | MET | E | 456 | −14.918 | 40.948 | 45.879 | 1.00 | 16.82 | E | C |
| ATOM | 8032 | CG | MET | E | 456 | −15.278 | 41.781 | 44.675 | 1.00 | 16.47 | E | C |
| ATOM | 8033 | SD | MET | E | 456 | −14.177 | 43.201 | 44.526 | 1.00 | 20.47 | E | S |
| ATOM | 8034 | CE | MET | E | 456 | −12.572 | 42.458 | 44.797 | 1.00 | 16.05 | E | C |
| ATOM | 8035 | C | MET | E | 456 | −15.378 | 39.030 | 47.376 | 1.00 | 15.57 | E | C |
| ATOM | 8036 | O | MET | E | 456 | −16.104 | 39.094 | 48.365 | 1.00 | 14.46 | E | O |
| ATOM | 8037 | N | ILE | E | 457 | −14.217 | 38.385 | 47.368 | 1.00 | 16.87 | E | N |
| ATOM | 8038 | CA | ILE | E | 457 | −13.712 | 37.706 | 48.555 | 1.00 | 16.96 | E | C |
| ATOM | 8039 | CB | ILE | E | 457 | −13.585 | 36.171 | 48.318 | 1.00 | 18.41 | E | C |
| ATOM | 8040 | CG2 | ILE | E | 457 | −12.512 | 35.569 | 49.219 | 1.00 | 15.65 | E | C |
| ATOM | 8041 | CG1 | ILE | E | 457 | −14.917 | 35.493 | 48.644 | 1.00 | 19.53 | E | C |
| ATOM | 8042 | CD1 | ILE | E | 457 | −15.521 | 34.793 | 47.487 | 1.00 | 21.32 | E | C |
| ATOM | 8043 | C | ILE | E | 457 | −12.355 | 38.285 | 48.931 | 1.00 | 17.28 | E | C |
| ATOM | 8044 | O | ILE | E | 457 | −11.484 | 38.459 | 48.084 | 1.00 | 14.75 | E | O |
| ATOM | 8045 | N | GLN | E | 458 | −12.184 | 38.606 | 50.209 | 1.00 | 17.38 | E | N |
| ATOM | 8046 | CA | GLN | E | 458 | −10.916 | 39.150 | 50.668 | 1.00 | 16.69 | E | C |
| ATOM | 8047 | CB | GLN | E | 458 | −11.131 | 40.473 | 51.407 | 1.00 | 17.81 | E | C |
| ATOM | 8048 | CG | GLN | E | 458 | −11.970 | 40.344 | 52.657 | 1.00 | 18.92 | E | C |
| ATOM | 8049 | CD | GLN | E | 458 | −12.106 | 41.649 | 53.415 | 1.00 | 21.20 | E | C |
| ATOM | 8050 | OE1 | GLN | E | 458 | −11.914 | 42.734 | 52.863 | 1.00 | 20.75 | E | O |
| ATOM | 8051 | NE2 | GLN | E | 458 | −12.445 | 41.547 | 54.696 | 1.00 | 20.32 | E | N |
| ATOM | 8052 | C | GLN | E | 458 | −10.269 | 38.147 | 51.601 | 1.00 | 16.18 | E | C |
| ATOM | 8053 | O | GLN | E | 458 | −10.941 | 37.512 | 52.414 | 1.00 | 16.16 | E | O |
| ATOM | 8054 | N | VAL | E | 459 | −8.968 | 37.968 | 51.461 | 1.00 | 15.64 | E | N |
| ATOM | 8055 | CA | VAL | E | 459 | −8.282 | 37.064 | 52.342 | 1.00 | 15.17 | E | C |
| ATOM | 8056 | CB | VAL | E | 459 | −7.767 | 35.777 | 51.598 | 1.00 | 15.62 | E | C |
| ATOM | 8057 | CG1 | VAL | E | 459 | −8.361 | 35.699 | 50.214 | 1.00 | 14.24 | E | C |
| ATOM | 8058 | CG2 | VAL | E | 459 | −6.259 | 35.718 | 51.571 | 1.00 | 14.61 | E | C |
| ATOM | 8059 | C | VAL | E | 459 | −7.171 | 37.848 | 53.031 | 1.00 | 16.94 | E | C |
| ATOM | 8060 | O | VAL | E | 459 | −6.203 | 38.287 | 52.406 | 1.00 | 16.38 | E | O |
| ATOM | 8061 | N | PRO | E | 460 | −7.347 | 38.097 | 54.343 | 1.00 | 18.72 | E | N |
| ATOM | 8062 | CD | PRO | E | 460 | −8.542 | 37.709 | 55.120 | 1.00 | 17.32 | E | C |
| ATOM | 8063 | CA | PRO | E | 460 | −6.381 | 38.836 | 55.163 | 1.00 | 16.62 | E | C |
| ATOM | 8064 | CB | PRO | E | 460 | −7.048 | 38.886 | 56.538 | 1.00 | 17.31 | E | C |
| ATOM | 8065 | CG | PRO | E | 460 | −8.521 | 38.671 | 56.259 | 1.00 | 18.74 | E | C |
| ATOM | 8066 | C | PRO | E | 460 | −5.022 | 38.146 | 55.194 | 1.00 | 16.93 | E | C |
| ATOM | 8067 | O | PRO | E | 460 | −4.938 | 36.922 | 55.203 | 1.00 | 17.33 | E | O |
| ATOM | 8068 | N | ARG | E | 461 | −3.954 | 38.932 | 55.189 | 1.00 | 17.19 | E | N |
| ATOM | 8069 | CA | ARG | E | 461 | −2.616 | 38.367 | 55.213 | 1.00 | 17.55 | E | C |
| ATOM | 8070 | CB | ARG | E | 461 | −1.642 | 39.317 | 54.508 | 1.00 | 15.77 | E | C |
| ATOM | 8071 | CG | ARG | E | 461 | −2.139 | 39.817 | 53.164 | 1.00 | 14.15 | E | C |
| ATOM | 8072 | CD | ARG | E | 461 | −1.038 | 40.498 | 52.367 | 1.00 | 14.99 | E | C |
| ATOM | 8073 | NE | ARG | E | 461 | −0.802 | 41.878 | 52.795 | 1.00 | 15.50 | E | N |
| ATOM | 8074 | CZ | ARG | E | 461 | −1.591 | 42.908 | 52.508 | 1.00 | 15.22 | E | C |
| ATOM | 8075 | NH1 | ARG | E | 461 | −2.688 | 42.743 | 51.781 | 1.00 | 16.37 | E | N |
| ATOM | 8076 | NH2 | ARG | E | 461 | −1.274 | 44.115 | 52.942 | 1.00 | 18.75 | E | N |
| ATOM | 8077 | C | ARG | E | 461 | −2.188 | 38.134 | 56.666 | 1.00 | 19.51 | E | C |
| ATOM | 8078 | O | ARG | E | 461 | −1.272 | 38.791 | 57.179 | 1.00 | 21.67 | E | O |
| ATOM | 8079 | N | ILE | E | 462 | −2.859 | 37.198 | 57.329 | 1.00 | 20.40 | E | N |
| ATOM | 8080 | CA | ILE | E | 462 | −2.556 | 36.900 | 58.726 | 1.00 | 19.51 | E | C |
| ATOM | 8081 | CB | ILE | E | 462 | −3.768 | 37.207 | 59.642 | 1.00 | 18.14 | E | C |
| ATOM | 8082 | CG2 | ILE | E | 462 | −4.128 | 38.675 | 59.541 | 1.00 | 16.17 | E | C |
| ATOM | 8083 | CG1 | ILE | E | 462 | −4.961 | 36.325 | 59.263 | 1.00 | 17.94 | E | C |
| ATOM | 8084 | CD1 | ILE | E | 462 | −6.247 | 36.643 | 60.034 | 1.00 | 16.66 | E | C |
| ATOM | 8085 | C | ILE | E | 462 | −2.112 | 35.463 | 58.967 | 1.00 | 20.59 | E | C |
| ATOM | 8086 | O | ILE | E | 462 | −2.570 | 34.814 | 59.913 | 1.00 | 21.61 | E | O |
| ATOM | 8087 | N | TYR | E | 463 | −1.222 | 34.964 | 58.116 | 1.00 | 20.03 | E | N |
| ATOM | 8088 | CA | TYR | E | 463 | −0.723 | 33.608 | 58.273 | 1.00 | 21.12 | E | C |
| ATOM | 8089 | CB | TYR | E | 463 | 0.239 | 33.245 | 57.140 | 1.00 | 20.35 | E | C |
| ATOM | 8090 | CG | TYR | E | 463 | 1.230 | 32.165 | 57.529 | 1.00 | 19.95 | E | C |
| ATOM | 8091 | CD1 | TYR | E | 463 | 0.871 | 30.816 | 57.494 | 1.00 | 18.62 | E | C |
| ATOM | 8092 | CE1 | TYR | E | 463 | 1.757 | 29.825 | 57.904 | 1.00 | 18.83 | E | C |
| ATOM | 8093 | CD2 | TYR | E | 463 | 2.510 | 32.496 | 57.980 | 1.00 | 19.54 | E | C |
| ATOM | 8094 | CE2 | TYR | E | 463 | 3.404 | 31.517 | 58.391 | 1.00 | 18.65 | E | C |
| ATOM | 8095 | CZ | TYR | E | 463 | 3.021 | 30.185 | 58.353 | 1.00 | 20.46 | E | C |
| ATOM | 8096 | OH | TYR | E | 463 | 3.900 | 29.218 | 58.780 | 1.00 | 22.40 | E | O |
| ATOM | 8097 | C | TYR | E | 463 | 0.016 | 33.497 | 59.600 | 1.00 | 23.03 | E | C |
| ATOM | 8098 | O | TYR | E | 463 | −0.078 | 32.479 | 60.288 | 1.00 | 22.98 | E | O |
| ATOM | 8099 | N | ASP | E | 464 | 0.758 | 34.547 | 59.947 | 1.00 | 23.99 | E | N |
| ATOM | 8100 | CA | ASP | E | 464 | 1.528 | 34.573 | 61.186 | 1.00 | 25.03 | E | C |
| ATOM | 8101 | CB | ASP | E | 464 | 2.328 | 35.881 | 61.296 | 1.00 | 25.49 | E | C |
| ATOM | 8102 | CG | ASP | E | 464 | 1.468 | 37.126 | 61.108 | 1.00 | 29.16 | E | C |
| ATOM | 8103 | OD1 | ASP | E | 464 | 1.905 | 38.214 | 61.533 | 1.00 | 31.14 | E | O |
| ATOM | 8104 | OD2 | ASP | E | 464 | 0.361 | 37.033 | 60.540 | 1.00 | 32.87 | E | O |
| ATOM | 8105 | C | ASP | E | 464 | 0.635 | 34.395 | 62.412 | 1.00 | 25.79 | E | C |
| ATOM | 8106 | O | ASP | E | 464 | 1.018 | 33.739 | 63.381 | 1.00 | 26.54 | E | O |
| ATOM | 8107 | N | VAL | E | 465 | −0.557 | 34.976 | 62.368 | 1.00 | 25.77 | E | N |
| ATOM | 8108 | CA | VAL | E | 465 | −1.490 | 34.860 | 63.475 | 1.00 | 26.13 | E | C |
| ATOM | 8109 | CB | VAL | E | 465 | −2.706 | 35.785 | 63.267 | 1.00 | 24.66 | E | C |
| ATOM | 8110 | CG1 | VAL | E | 465 | −3.773 | 35.488 | 64.295 | 1.00 | 25.66 | E | C |
| ATOM | 8111 | CG2 | VAL | E | 465 | −2.271 | 37.235 | 63.369 | 1.00 | 24.13 | E | C |
| ATOM | 8112 | C | VAL | E | 465 | −1.958 | 33.408 | 63.605 | 1.00 | 28.87 | E | C |
| ATOM | 8113 | O | VAL | E | 465 | −1.918 | 32.837 | 64.696 | 1.00 | 29.28 | E | O |
| ATOM | 8114 | N | PHE | E | 466 | −2.383 | 32.813 | 62.488 | 1.00 | 30.43 | E | N |
| ATOM | 8115 | CA | PHE | E | 466 | −2.862 | 31.428 | 62.470 | 1.00 | 30.05 | E | C |
| ATOM | 8116 | CB | PHE | E | 466 | −3.443 | 31.077 | 61.095 | 1.00 | 30.37 | E | C |
| ATOM | 8117 | CG | PHE | E | 466 | −4.735 | 31.779 | 60.781 | 1.00 | 30.78 | E | C |
| ATOM | 8118 | CD1 | PHE | E | 466 | −5.708 | 31.950 | 61.759 | 1.00 | 30.60 | E | C |
| ATOM | 8119 | CD2 | PHE | E | 466 | −4.982 | 32.266 | 59.500 | 1.00 | 30.86 | E | C |
| ATOM | 8120 | CE1 | PHE | E | 466 | −6.908 | 32.595 | 61.470 | 1.00 | 31.81 | E | C |
| ATOM | 8121 | CE2 | PHE | E | 466 | −6.180 | 32.914 | 59.202 | 1.00 | 31.47 | E | C |
| ATOM | 8122 | CZ | PHE | E | 466 | −7.144 | 33.078 | 60.190 | 1.00 | 31.21 | E | C |
| ATOM | 8123 | C | PHE | E | 466 | −1.757 | 30.433 | 62.804 | 1.00 | 30.64 | E | C |
| ATOM | 8124 | O | PHE | E | 466 | −2.006 | 29.404 | 63.424 | 1.00 | 30.77 | E | O |
| ATOM | 8125 | N | ARG | E | 467 | −0.538 | 30.745 | 62.381 | 1.00 | 31.98 | E | N |
| ATOM | 8126 | CA | ARG | E | 467 | 0.613 | 29.883 | 62.621 | 1.00 | 32.78 | E | C |
| ATOM | 8127 | CB | ARG | E | 467 | 1.810 | 30.377 | 61.806 | 1.00 | 33.30 | E | C |
| ATOM | 8128 | CG | ARG | E | 467 | 3.087 | 29.605 | 62.056 | 1.00 | 34.58 | E | C |
| ATOM | 8129 | CD | ARG | E | 467 | 2.930 | 28.140 | 61.675 | 1.00 | 37.75 | E | C |
| ATOM | 8130 | NE | ARG | E | 467 | 4.155 | 27.394 | 61.934 | 1.00 | 40.19 | E | N |
| ATOM | 8131 | CZ | ARG | E | 467 | 4.587 | 27.083 | 63.152 | 1.00 | 45.51 | E | C |
| ATOM | 8132 | NH1 | ARG | E | 467 | 3.888 | 27.453 | 64.222 | 1.00 | 48.10 | E | N |
| ATOM | 8133 | NH2 | ARG | E | 467 | 5.731 | 26.430 | 63.306 | 1.00 | 46.80 | E | N |
| ATOM | 8134 | C | ARG | E | 467 | 1.001 | 29.825 | 64.095 | 1.00 | 34.36 | E | C |
| ATOM | 8135 | O | ARG | E | 467 | 1.252 | 28.748 | 64.637 | 1.00 | 35.13 | E | O |
| ATOM | 8136 | N | SER | E | 468 | 1.061 | 30.989 | 64.737 | 1.00 | 34.11 | E | N |
| ATOM | 8137 | CA | SER | E | 468 | 1.423 | 31.061 | 66.147 | 1.00 | 33.66 | E | C |
| ATOM | 8138 | CB | SER | E | 468 | 1.571 | 32.525 | 66.572 | 1.00 | 33.46 | E | C |
| ATOM | 8139 | OG | SER | E | 468 | 0.327 | 33.199 | 66.505 | 1.00 | 37.20 | E | O |
| ATOM | 8140 | C | SER | E | 468 | 0.382 | 30.353 | 67.021 | 1.00 | 33.07 | E | C |
| ATOM | 8141 | O | SER | E | 468 | 0.697 | 29.901 | 68.119 | 1.00 | 33.46 | E | O |
| ATOM | 8142 | N | LYS | E | 469 | −0.852 | 30.263 | 66.528 | 1.00 | 31.40 | E | N |
| ATOM | 8143 | CA | LYS | E | 469 | −1.937 | 29.598 | 67.241 | 1.00 | 30.37 | E | C |
| ATOM | 8144 | CB | LYS | E | 469 | −3.287 | 30.194 | 66.839 | 1.00 | 31.59 | E | C |
| ATOM | 8145 | CG | LYS | E | 469 | −3.737 | 31.399 | 67.647 | 1.00 | 33.61 | E | C |
| ATOM | 8146 | CD | LYS | E | 469 | −5.105 | 31.880 | 67.165 | 1.00 | 36.98 | E | C |
| ATOM | 8147 | CE | LYS | E | 469 | −5.636 | 33.025 | 68.012 | 1.00 | 37.84 | E | C |
| ATOM | 8148 | NZ | LYS | E | 469 | −4.675 | 34.156 | 68.072 | 1.00 | 40.48 | E | N |
| ATOM | 8149 | C | LYS | E | 469 | −1.926 | 28.123 | 66.856 | 1.00 | 31.77 | E | C |
| ATOM | 8150 | O | LYS | E | 469 | −2.741 | 27.332 | 67.329 | 1.00 | 31.24 | E | O |
| ATOM | 8151 | N | ASN | E | 470 | −1.000 | 27.764 | 65.977 | 1.00 | 33.30 | E | N |
| ATOM | 8152 | CA | ASN | E | 470 | −0.869 | 26.396 | 65.491 | 1.00 | 34.03 | E | C |
| ATOM | 8153 | CB | ASN | E | 470 | −0.485 | 25.472 | 66.637 | 1.00 | 36.86 | E | C |
| ATOM | 8154 | CG | ASN | E | 470 | 0.841 | 25.857 | 67.255 | 1.00 | 40.41 | E | C |
| ATOM | 8155 | OD1 | ASN | E | 470 | 1.896 | 25.678 | 66.645 | 1.00 | 41.21 | E | O |
| ATOM | 8156 | ND2 | ASN | E | 470 | 0.795 | 26.405 | 68.468 | 1.00 | 41.83 | E | N |
| ATOM | 8157 | C | ASN | E | 470 | −2.130 | 25.898 | 64.801 | 1.00 | 34.03 | E | C |
| ATOM | 8158 | O | ASN | E | 470 | −2.547 | 24.753 | 64.975 | 1.00 | 33.43 | E | O |
| ATOM | 8159 | N | PHE | E | 471 | −2.733 | 26.779 | 64.012 | 1.00 | 34.07 | E | N |
| ATOM | 8160 | CA | PHE | E | 471 | −3.923 | 26.447 | 63.253 | 1.00 | 33.12 | E | C |
| ATOM | 8161 | CB | PHE | E | 471 | −4.749 | 27.706 | 62.968 | 1.00 | 34.57 | E | C |
| ATOM | 8162 | CG | PHE | E | 471 | −5.695 | 28.078 | 64.069 | 1.00 | 37.15 | E | C |
| ATOM | 8163 | CD1 | PHE | E | 471 | −5.933 | 27.208 | 65.129 | 1.00 | 39.31 | E | C |
| ATOM | 8164 | CD2 | PHE | E | 471 | −6.357 | 29.298 | 64.042 | 1.00 | 39.39 | E | C |
| ATOM | 8165 | CE1 | PHE | E | 471 | −6.820 | 27.549 | 66.150 | 1.00 | 41.06 | E | C |
| ATOM | 8166 | CE2 | PHE | E | 471 | −7.247 | 29.652 | 65.056 | 1.00 | 41.95 | E | C |
| ATOM | 8167 | CZ | PHE | E | 471 | −7.480 | 28.775 | 66.114 | 1.00 | 42.20 | E | C |
| ATOM | 8168 | C | PHE | E | 471 | −3.424 | 25.868 | 61.941 | 1.00 | 32.19 | E | C |
| ATOM | 8169 | O | PHE | E | 471 | −4.141 | 25.123 | 61.279 | 1.00 | 33.74 | E | O |
| ATOM | 8170 | N | LEU | E | 472 | −2.190 | 26.220 | 61.578 | 1.00 | 30.11 | E | N |
| ATOM | 8171 | CA | LEU | E | 472 | −1.569 | 25.765 | 60.335 | 1.00 | 29.54 | E | C |
| ATOM | 8172 | CB | LEU | E | 472 | −1.654 | 26.851 | 59.244 | 1.00 | 29.21 | E | C |
| ATOM | 8173 | CG | LEU | E | 472 | −2.989 | 27.524 | 58.920 | 1.00 | 29.11 | E | C |
| ATOM | 8174 | CD1 | LEU | E | 472 | −2.732 | 28.865 | 58.246 | 1.00 | 30.27 | E | C |
| ATOM | 8175 | CD2 | LEU | E | 472 | −3.810 | 26.618 | 58.023 | 1.00 | 27.71 | E | C |
| ATOM | 8176 | C | LEU | E | 472 | −0.098 | 25.424 | 60.545 | 1.00 | 28.92 | E | C |
| ATOM | 8177 | O | LEU | E | 472 | 0.570 | 26.005 | 61.400 | 1.00 | 31.14 | E | O |
| ATOM | 8178 | N | PRO | E | 473 | 0.426 | 24.472 | 59.762 | 1.00 | 27.72 | E | N |
| ATOM | 8179 | CD | PRO | E | 473 | −0.307 | 23.688 | 58.754 | 1.00 | 26.32 | E | C |
| ATOM | 8180 | CA | PRO | E | 473 | 1.828 | 24.057 | 59.857 | 1.00 | 27.33 | E | C |
| ATOM | 8181 | CB | PRO | E | 473 | 1.790 | 22.595 | 59.436 | 1.00 | 26.39 | E | C |
| ATOM | 8182 | CG | PRO | E | 473 | 0.577 | 22.484 | 58.536 | 1.00 | 25.25 | E | C |
| ATOM | 8183 | C | PRO | E | 473 | 2.774 | 24.876 | 58.968 | 1.00 | 28.96 | E | C |
| ATOM | 8184 | O | PRO | E | 473 | 3.953 | 25.043 | 59.293 | 1.00 | 29.34 | E | O |
| ATOM | 8185 | N | HIS | E | 474 | 2.253 | 25.382 | 57.849 | 1.00 | 28.24 | E | N |
| ATOM | 8186 | CA | HIS | E | 474 | 3.048 | 26.168 | 56.901 | 1.00 | 26.38 | E | C |
| ATOM | 8187 | CB | HIS | E | 474 | 3.892 | 25.230 | 56.039 | 1.00 | 24.85 | E | C |
| ATOM | 8188 | CG | HIS | E | 474 | 3.089 | 24.164 | 55.363 | 1.00 | 25.12 | E | C |
| ATOM | 8189 | CD2 | HIS | E | 474 | 2.122 | 24.242 | 54.418 | 1.00 | 26.80 | E | C |
| ATOM | 8190 | ND1 | HIS | E | 474 | 3.200 | 22.829 | 55.685 | 1.00 | 26.26 | E | N |
| ATOM | 8191 | CE1 | HIS | E | 474 | 2.335 | 22.130 | 54.970 | 1.00 | 25.12 | E | C |
| ATOM | 8192 | NE2 | HIS | E | 474 | 1.668 | 22.964 | 54.194 | 1.00 | 25.70 | E | N |
| ATOM | 8193 | C | HIS | E | 474 | 2.138 | 27.014 | 56.002 | 1.00 | 26.25 | E | C |
| ATOM | 8194 | O | HIS | E | 474 | 0.914 | 26.868 | 56.035 | 1.00 | 24.18 | E | O |
| ATOM | 8195 | N | PHE | E | 475 | 2.743 | 27.881 | 55.192 | 1.00 | 25.52 | E | N |
| ATOM | 8196 | CA | PHE | E | 475 | 1.981 | 28.756 | 54.301 | 1.00 | 25.29 | E | C |
| ATOM | 8197 | CB | PHE | E | 475 | 2.903 | 29.801 | 53.668 | 1.00 | 23.97 | E | C |
| ATOM | 8198 | CG | PHE | E | 475 | 2.168 | 30.962 | 53.054 | 1.00 | 25.24 | E | C |
| ATOM | 8199 | CD1 | PHE | E | 475 | 2.204 | 31.178 | 51.675 | 1.00 | 23.43 | E | C |
| ATOM | 8200 | CD2 | PHE | E | 475 | 1.433 | 31.839 | 53.852 | 1.00 | 24.83 | E | C |
| ATOM | 8201 | CE1 | PHE | E | 475 | 1.520 | 32.249 | 51.100 | 1.00 | 23.10 | E | C |
| ATOM | 8202 | CE2 | PHE | E | 475 | 0.743 | 32.915 | 53.285 | 1.00 | 25.50 | E | C |
| ATOM | 8203 | CZ | PHE | E | 475 | 0.789 | 33.118 | 51.902 | 1.00 | 24.28 | E | C |
| ATOM | 8204 | C | PHE | E | 475 | 1.235 | 27.998 | 53.206 | 1.00 | 24.77 | E | C |
| ATOM | 8205 | O | PHE | E | 475 | 0.145 | 28.402 | 52.792 | 1.00 | 24.33 | E | O |
| ATOM | 8206 | N | GLY | E | 476 | 1.820 | 26.897 | 52.745 | 1.00 | 24.60 | E | N |
| ATOM | 8207 | CA | GLY | E | 476 | 1.191 | 26.109 | 51.699 | 1.00 | 23.95 | E | C |
| ATOM | 8208 | C | GLY | E | 476 | −0.192 | 25.632 | 52.084 | 1.00 | 24.16 | E | C |
| ATOM | 8209 | O | GLY | E | 476 | −1.083 | 25.521 | 51.238 | 1.00 | 24.08 | E | O |
| ATOM | 8210 | N | LYS | E | 477 | −0.377 | 25.354 | 53.372 | 1.00 | 24.27 | E | N |
| ATOM | 8211 | CA | LYS | E | 477 | −1.659 | 24.882 | 53.872 | 1.00 | 22.53 | E | C |
| ATOM | 8212 | CB | LYS | E | 477 | −1.491 | 24.299 | 55.273 | 1.00 | 22.61 | E | C |
| ATOM | 8213 | CG | LYS | E | 477 | −2.759 | 23.700 | 55.840 | 1.00 | 24.37 | E | C |
| ATOM | 8214 | CD | LYS | E | 477 | −3.192 | 22.462 | 55.069 | 1.00 | 25.70 | E | C |
| ATOM | 8215 | CE | LYS | E | 477 | −4.568 | 22.011 | 55.512 | 1.00 | 27.24 | E | C |
| ATOM | 8216 | NZ | LYS | E | 477 | −4.986 | 20.756 | 54.832 | 1.00 | 31.29 | E | N |
| ATOM | 8217 | C | LYS | E | 477 | −2.701 | 25.990 | 53.884 | 1.00 | 21.97 | E | C |
| ATOM | 8218 | O | LYS | E | 477 | −3.899 | 25.718 | 53.831 | 1.00 | 21.73 | E | O |
| ATOM | 8219 | N | MET | E | 478 | −2.250 | 27.239 | 53.960 | 1.00 | 23.17 | E | N |
| ATOM | 8220 | CA | MET | E | 478 | −3.177 | 28.368 | 53.947 | 1.00 | 22.59 | E | C |
| ATOM | 8221 | CB | MET | E | 478 | −2.486 | 29.662 | 54.401 | 1.00 | 23.67 | E | C |
| ATOM | 8222 | CG | MET | E | 478 | −3.472 | 30.776 | 54.756 | 1.00 | 22.48 | E | C |
| ATOM | 8223 | SD | MET | E | 478 | −2.689 | 32.344 | 55.128 | 1.00 | 26.32 | E | S |
| ATOM | 8224 | CE | MET | E | 478 | −4.097 | 33.426 | 55.276 | 1.00 | 22.05 | E | C |
| ATOM | 8225 | C | MET | E | 478 | −3.682 | 28.536 | 52.519 | 1.00 | 21.80 | E | C |
| ATOM | 8226 | O | MET | E | 478 | −4.884 | 28.708 | 52.286 | 1.00 | 22.24 | E | O |
| ATOM | 8227 | N | LEU | E | 479 | −2.749 | 28.476 | 51.571 | 1.00 | 21.96 | E | N |
| ATOM | 8228 | CA | LEU | E | 479 | −3.064 | 28.612 | 50.152 | 1.00 | 22.00 | E | C |
| ATOM | 8229 | CB | LEU | E | 479 | −1.778 | 28.531 | 49.322 | 1.00 | 18.98 | E | C |
| ATOM | 8230 | CG | LEU | E | 479 | −0.828 | 29.729 | 49.363 | 1.00 | 16.48 | E | C |
| ATOM | 8231 | CD1 | LEU | E | 479 | 0.425 | 29.406 | 48.568 | 1.00 | 17.83 | E | C |
| ATOM | 8232 | CD2 | LEU | E | 479 | −1.507 | 30.952 | 48.788 | 1.00 | 17.27 | E | C |
| ATOM | 8233 | C | LEU | E | 479 | −4.024 | 27.497 | 49.746 | 1.00 | 22.11 | E | C |
| ATOM | 8234 | O | LEU | E | 479 | −4.962 | 27.709 | 48.973 | 1.00 | 21.87 | E | O |
| ATOM | 8235 | N | GLU | E | 480 | −3.791 | 26.309 | 50.289 | 1.00 | 23.80 | E | N |
| ATOM | 8236 | CA | GLU | E | 480 | −4.636 | 25.159 | 49.993 | 1.00 | 25.38 | E | C |
| ATOM | 8237 | CB | GLU | E | 480 | −4.049 | 23.901 | 50.632 | 1.00 | 26.81 | E | C |
| ATOM | 8238 | CG | GLU | E | 480 | −5.042 | 22.775 | 50.790 | 1.00 | 30.89 | E | C |
| ATOM | 8239 | CD | GLU | E | 480 | −4.368 | 21.420 | 50.854 | 1.00 | 34.86 | E | C |
| ATOM | 8240 | OE1 | GLU | E | 480 | −3.126 | 21.377 | 51.014 | 1.00 | 35.28 | E | O |
| ATOM | 8241 | OE2 | GLU | E | 480 | −5.080 | 20.399 | 50.747 | 1.00 | 37.16 | E | O |
| ATOM | 8242 | C | GLU | E | 480 | −6.070 | 25.366 | 50.476 | 1.00 | 24.19 | E | C |
| ATOM | 8243 | O | GLU | E | 480 | −7.020 | 25.102 | 49.740 | 1.00 | 23.68 | E | O |
| ATOM | 8244 | N | ASN | E | 481 | −6.229 | 25.833 | 51.710 | 1.00 | 23.87 | E | N |
| ATOM | 8245 | CA | ASN | E | 481 | −7.560 | 26.075 | 52.262 | 1.00 | 22.52 | E | C |
| ATOM | 8246 | CB | ASN | E | 481 | −7.465 | 26.486 | 53.729 | 1.00 | 25.07 | E | C |
| ATOM | 8247 | CG | ASN | E | 481 | −6.939 | 25.377 | 54.611 | 1.00 | 26.28 | E | C |
| ATOM | 8248 | OD1 | ASN | E | 481 | −6.317 | 25.636 | 55.637 | 1.00 | 28.90 | E | O |
| ATOM | 8249 | ND2 | ASN | E | 481 | −7.185 | 24.131 | 54.216 | 1.00 | 26.70 | E | N |
| ATOM | 8250 | C | ASN | E | 481 | −8.279 | 27.167 | 51.490 | 1.00 | 21.54 | E | C |
| ATOM | 8251 | O | ASN | E | 481 | −9.505 | 27.156 | 51.376 | 1.00 | 20.36 | E | O |
| ATOM | 8252 | N | VAL | E | 482 | −7.516 | 28.118 | 50.962 | 1.00 | 20.95 | E | N |
| ATOM | 8253 | CA | VAL | E | 482 | −8.111 | 29.204 | 50.195 | 1.00 | 21.35 | E | C |
| ATOM | 8254 | CB | VAL | E | 482 | −7.146 | 30.410 | 50.066 | 1.00 | 20.92 | E | C |
| ATOM | 8255 | CG1 | VAL | E | 482 | −7.753 | 31.468 | 49.156 | 1.00 | 19.27 | E | C |
| ATOM | 8256 | CG2 | VAL | E | 482 | −6.872 | 31.011 | 51.444 | 1.00 | 20.39 | E | C |
| ATOM | 8257 | C | VAL | E | 482 | −8.530 | 28.779 | 48.789 | 1.00 | 21.33 | E | C |
| ATOM | 8258 | O | VAL | E | 482 | −9.659 | 29.038 | 48.366 | 1.00 | 21.89 | E | O |
| ATOM | 8259 | N | PHE | E | 483 | −7.639 | 28.102 | 48.071 | 1.00 | 22.21 | E | N |
| ATOM | 8260 | CA | PHE | E | 483 | −7.947 | 27.722 | 46.694 | 1.00 | 23.09 | E | C |
| ATOM | 8261 | CB | PHE | E | 483 | −6.740 | 28.046 | 45.805 | 1.00 | 21.29 | E | C |
| ATOM | 8262 | CG | PHE | E | 483 | −6.391 | 29.512 | 45.768 | 1.00 | 19.18 | E | C |
| ATOM | 8263 | CD1 | PHE | E | 483 | −7.231 | 30.428 | 45.144 | 1.00 | 19.48 | E | C |
| ATOM | 8264 | CD2 | PHE | E | 483 | −5.237 | 29.979 | 46.381 | 1.00 | 18.26 | E | C |
| ATOM | 8265 | CE1 | PHE | E | 483 | −6.928 | 31.789 | 45.138 | 1.00 | 18.57 | E | C |
| ATOM | 8266 | CE2 | PHE | E | 483 | −4.925 | 31.337 | 46.378 | 1.00 | 18.47 | E | C |
| ATOM | 8267 | CZ | PHE | E | 483 | −5.772 | 32.241 | 45.758 | 1.00 | 18.47 | E | C |
| ATOM | 8268 | C | PHE | E | 483 | −8.449 | 26.310 | 46.374 | 1.00 | 23.81 | E | C |
| ATOM | 8269 | O | PHE | E | 483 | −9.285 | 26.146 | 45.490 | 1.00 | 25.15 | E | O |
| ATOM | 8270 | N | MET | E | 484 | −7.965 | 25.295 | 47.074 | 1.00 | 25.14 | E | N |
| ATOM | 8271 | CA | MET | E | 484 | −8.394 | 23.928 | 46.786 | 1.00 | 26.14 | E | C |
| ATOM | 8272 | CB | MET | E | 484 | −7.769 | 22.962 | 47.794 | 1.00 | 29.16 | E | C |
| ATOM | 8273 | CG | MET | E | 484 | −7.874 | 21.485 | 47.403 | 1.00 | 33.00 | E | C |
| ATOM | 8274 | SD | MET | E | 484 | −7.032 | 21.041 | 45.854 | 1.00 | 37.37 | E | S |
| ATOM | 8275 | CE | MET | E | 484 | −5.351 | 20.844 | 46.390 | 1.00 | 31.87 | E | C |
| ATOM | 8276 | C | MET | E | 484 | −9.912 | 23.699 | 46.725 | 1.00 | 25.58 | E | C |
| ATOM | 8277 | O | MET | E | 484 | −10.414 | 23.063 | 45.797 | 1.00 | 25.37 | E | O |
| ATOM | 8278 | N | PRO | E | 485 | −10.667 | 24.208 | 47.709 | 1.00 | 25.64 | E | N |
| ATOM | 8279 | CD | PRO | E | 485 | −10.258 | 24.973 | 48.896 | 1.00 | 25.35 | E | C |
| ATOM | 8280 | CA | PRO | E | 485 | −12.118 | 24.000 | 47.673 | 1.00 | 24.82 | E | C |
| ATOM | 8281 | CB | PRO | E | 485 | −12.616 | 24.700 | 48.936 | 1.00 | 24.41 | E | C |
| ATOM | 8282 | CG | PRO | E | 485 | −11.417 | 24.783 | 49.819 | 1.00 | 25.54 | E | C |
| ATOM | 8283 | C | PRO | E | 485 | −12.785 | 24.556 | 46.419 | 1.00 | 25.06 | E | C |
| ATOM | 8284 | O | PRO | E | 485 | −13.731 | 23.966 | 45.891 | 1.00 | 24.68 | E | O |
| ATOM | 8285 | N | VAL | E | 486 | −12.293 | 25.699 | 45.954 | 1.00 | 24.93 | E | N |
| ATOM | 8286 | CA | VAL | E | 486 | −12.840 | 26.341 | 44.769 | 1.00 | 24.08 | E | C |
| ATOM | 8287 | CB | VAL | E | 486 | −12.327 | 27.781 | 44.647 | 1.00 | 25.19 | E | C |
| ATOM | 8288 | CG1 | VAL | E | 486 | −13.137 | 28.533 | 43.620 | 1.00 | 27.06 | E | C |
| ATOM | 8289 | CG2 | VAL | E | 486 | −12.432 | 28.475 | 45.991 | 1.00 | 27.59 | E | C |
| ATOM | 8290 | C | VAL | E | 486 | −12.483 | 25.553 | 43.509 | 1.00 | 23.87 | E | C |
| ATOM | 8291 | O | VAL | E | 486 | −13.274 | 25.478 | 42.573 | 1.00 | 23.28 | E | O |
| ATOM | 8292 | N | PHE | E | 487 | −11.292 | 24.965 | 43.485 | 1.00 | 24.00 | E | N |
| ATOM | 8293 | CA | PHE | E | 487 | −10.875 | 24.167 | 42.343 | 1.00 | 26.04 | E | C |
| ATOM | 8294 | CB | PHE | E | 487 | −9.407 | 23.764 | 42.468 | 1.00 | 26.81 | E | C |
| ATOM | 8295 | CG | PHE | E | 487 | −8.453 | 24.746 | 41.851 | 1.00 | 26.17 | E | C |
| ATOM | 8296 | CD1 | PHE | E | 487 | −7.884 | 25.759 | 42.616 | 1.00 | 25.54 | E | C |
| ATOM | 8297 | CD2 | PHE | E | 487 | −8.113 | 24.650 | 40.505 | 1.00 | 27.78 | E | C |
| ATOM | 8298 | CE1 | PHE | E | 487 | −6.985 | 26.665 | 42.053 | 1.00 | 26.33 | E | C |
| ATOM | 8299 | CE2 | PHE | E | 487 | −7.216 | 25.549 | 39.927 | 1.00 | 26.99 | E | C |
| ATOM | 8300 | CZ | PHE | E | 487 | −6.650 | 26.559 | 40.702 | 1.00 | 27.35 | E | C |
| ATOM | 8301 | C | PHE | E | 487 | −11.741 | 22.916 | 42.312 | 1.00 | 27.98 | E | C |
| ATOM | 8302 | O | PHE | E | 487 | −12.139 | 22.453 | 41.245 | 1.00 | 28.62 | E | O |
| ATOM | 8303 | N | GLU | E | 488 | −12.038 | 22.379 | 43.492 | 1.00 | 28.95 | E | N |
| ATOM | 8304 | CA | GLU | E | 488 | −12.866 | 21.184 | 43.615 | 1.00 | 28.89 | E | C |
| ATOM | 8305 | CB | GLU | E | 488 | −12.971 | 20.760 | 45.081 | 1.00 | 31.44 | E | C |
| ATOM | 8306 | CG | GLU | E | 488 | −12.314 | 19.426 | 45.381 | 1.00 | 37.08 | E | C |
| ATOM | 8307 | CD | GLU | E | 488 | −11.536 | 19.442 | 46.689 | 1.00 | 41.58 | E | C |
| ATOM | 8308 | OE1 | GLU | E | 488 | −11.950 | 20.171 | 47.624 | 1.00 | 43.03 | E | O |
| ATOM | 8309 | OE2 | GLU | E | 488 | −10.513 | 18.725 | 46.781 | 1.00 | 42.29 | E | O |
| ATOM | 8310 | C | GLU | E | 488 | −14.268 | 21.391 | 43.058 | 1.00 | 26.99 | E | C |
| ATOM | 8311 | O | GLU | E | 488 | −14.800 | 20.523 | 42.376 | 1.00 | 25.53 | E | O |
| ATOM | 8312 | N | ALA | E | 489 | −14.870 | 22.535 | 43.360 | 1.00 | 25.44 | E | N |
| ATOM | 8313 | CA | ALA | E | 489 | −16.214 | 22.828 | 42.875 | 1.00 | 25.88 | E | C |
| ATOM | 8314 | CB | ALA | E | 489 | −16.781 | 24.037 | 43.618 | 1.00 | 23.12 | E | C |
| ATOM | 8315 | C | ALA | E | 489 | −16.218 | 23.085 | 41.362 | 1.00 | 27.11 | E | C |
| ATOM | 8316 | O | ALA | E | 489 | −17.243 | 22.919 | 40.699 | 1.00 | 26.44 | E | O |
| ATOM | 8317 | N | THR | E | 490 | −15.072 | 23.496 | 40.824 | 1.00 | 27.70 | E | N |
| ATOM | 8318 | CA | THR | E | 490 | −14.941 | 23.773 | 39.394 | 1.00 | 28.92 | E | C |
| ATOM | 8319 | CB | THR | E | 490 | −13.613 | 24.526 | 39.088 | 1.00 | 28.57 | E | C |
| ATOM | 8320 | OG1 | THR | E | 490 | −13.695 | 25.860 | 39.597 | 1.00 | 30.07 | E | O |
| ATOM | 8321 | CG2 | THR | E | 490 | −13.354 | 24.591 | 37.589 | 1.00 | 28.31 | E | C |
| ATOM | 8322 | C | THR | E | 490 | −14.955 | 22.456 | 38.619 | 1.00 | 29.18 | E | C |
| ATOM | 8323 | O | THR | E | 490 | −15.715 | 22.283 | 37.664 | 1.00 | 27.82 | E | O |
| ATOM | 8324 | N | ILE | E | 491 | −14.107 | 21.535 | 39.060 | 1.00 | 29.45 | E | N |
| ATOM | 8325 | CA | ILE | E | 491 | −13.970 | 20.225 | 38.449 | 1.00 | 30.20 | E | C |
| ATOM | 8326 | CB | ILE | E | 491 | −12.718 | 19.517 | 39.023 | 1.00 | 29.68 | E | C |
| ATOM | 8327 | CG2 | ILE | E | 491 | −13.000 | 18.071 | 39.336 | 1.00 | 31.98 | E | C |
| ATOM | 8328 | CG1 | ILE | E | 491 | −11.576 | 19.624 | 38.022 | 1.00 | 30.73 | E | C |
| ATOM | 8329 | CD1 | ILE | E | 491 | −10.406 | 20.425 | 38.538 | 1.00 | 31.60 | E | C |
| ATOM | 8330 | C | ILE | E | 491 | −15.220 | 19.350 | 38.632 | 1.00 | 30.70 | E | C |
| ATOM | 8331 | O | ILE | E | 491 | −15.587 | 18.605 | 37.725 | 1.00 | 30.82 | E | O |
| ATOM | 8332 | N | ASN | E | 492 | −15.875 | 19.449 | 39.791 | 1.00 | 30.58 | E | N |
| ATOM | 8333 | CA | ASN | E | 492 | −17.081 | 18.660 | 40.080 | 1.00 | 29.84 | E | C |
| ATOM | 8334 | CB | ASN | E | 492 | −16.769 | 17.587 | 41.124 | 1.00 | 30.38 | E | C |
| ATOM | 8335 | CG | ASN | E | 492 | −15.603 | 16.703 | 40.723 | 1.00 | 33.35 | E | C |
| ATOM | 8336 | OD1 | ASN | E | 492 | −15.570 | 16.160 | 39.616 | 1.00 | 33.16 | E | O |
| ATOM | 8337 | ND2 | ASN | E | 492 | −14.633 | 16.555 | 41.623 | 1.00 | 34.29 | E | N |
| ATOM | 8338 | C | ASN | E | 492 | −18.230 | 19.527 | 40.590 | 1.00 | 29.32 | E | C |
| ATOM | 8339 | O | ASN | E | 492 | −18.636 | 19.420 | 41.746 | 1.00 | 29.00 | E | O |
| ATOM | 8340 | N | PRO | E | 493 | −18.789 | 20.381 | 39.721 | 1.00 | 29.83 | E | N |
| ATOM | 8341 | CD | PRO | E | 493 | −18.436 | 20.562 | 38.301 | 1.00 | 28.90 | E | C |
| ATOM | 8342 | CA | PRO | E | 493 | −19.892 | 21.257 | 40.129 | 1.00 | 30.61 | E | C |
| ATOM | 8343 | CB | PRO | E | 493 | −20.302 | 21.957 | 38.829 | 1.00 | 29.82 | E | C |
| ATOM | 8344 | CG | PRO | E | 493 | −19.112 | 21.851 | 37.943 | 1.00 | 28.54 | E | C |
| ATOM | 8345 | C | PRO | E | 493 | −21.072 | 20.542 | 40.782 | 1.00 | 31.99 | E | C |
| ATOM | 8346 | O | PRO | E | 493 | −21.738 | 21.100 | 41.659 | 1.00 | 32.66 | E | O |
| ATOM | 8347 | N | GLN | E | 494 | −21.333 | 19.313 | 40.357 | 1.00 | 31.95 | E | N |
| ATOM | 8348 | CA | GLN | E | 494 | −22.459 | 18.559 | 40.893 | 1.00 | 34.06 | E | C |
| ATOM | 8349 | CB | GLN | E | 494 | −22.746 | 17.355 | 39.999 | 1.00 | 36.54 | E | C |
| ATOM | 8350 | CG | GLN | E | 494 | −22.952 | 17.726 | 38.546 | 1.00 | 40.40 | E | C |
| ATOM | 8351 | CD | GLN | E | 494 | −24.390 | 18.089 | 38.236 | 1.00 | 41.46 | E | C |
| ATOM | 8352 | OE1 | GLN | E | 494 | −24.918 | 17.708 | 37.196 | 1.00 | 46.23 | E | O |
| ATOM | 8353 | NE2 | GLN | E | 494 | −25.030 | 18.826 | 39.137 | 1.00 | 41.02 | E | N |
| ATOM | 8354 | C | GLN | E | 494 | −22.260 | 18.098 | 42.332 | 1.00 | 32.79 | E | C |
| ATOM | 8355 | O | GLN | E | 494 | −23.218 | 18.018 | 43.104 | 1.00 | 31.49 | E | O |
| ATOM | 8356 | N | ALA | E | 495 | −21.015 | 17.792 | 42.681 | 1.00 | 30.98 | E | N |
| ATOM | 8357 | CA | ALA | E | 495 | −20.682 | 17.343 | 44.022 | 1.00 | 28.96 | E | C |
| ATOM | 8358 | CB | ALA | E | 495 | −19.276 | 16.752 | 44.034 | 1.00 | 26.76 | E | C |
| ATOM | 8359 | C | ALA | E | 495 | −20.773 | 18.513 | 44.997 | 1.00 | 29.21 | E | C |
| ATOM | 8360 | O | ALA | E | 495 | −20.999 | 18.319 | 46.194 | 1.00 | 29.59 | E | O |
| ATOM | 8361 | N | HIS | E | 496 | −20.605 | 19.727 | 44.475 | 1.00 | 29.71 | E | N |
| ATOM | 8362 | CA | HIS | E | 496 | −20.657 | 20.943 | 45.289 | 1.00 | 28.73 | E | C |
| ATOM | 8363 | CB | HIS | E | 496 | −19.255 | 21.524 | 45.443 | 1.00 | 27.93 | E | C |
| ATOM | 8364 | CG | HIS | E | 496 | −18.218 | 20.506 | 45.793 | 1.00 | 27.63 | E | C |
| ATOM | 8365 | CD2 | HIS | E | 496 | −17.264 | 19.912 | 45.039 | 1.00 | 28.77 | E | C |
| ATOM | 8366 | ND1 | HIS | E | 496 | −18.070 | 20.001 | 47.067 | 1.00 | 29.21 | E | N |
| ATOM | 8367 | CE1 | HIS | E | 496 | −17.065 | 19.143 | 47.083 | 1.00 | 30.33 | E | C |
| ATOM | 8368 | NE2 | HIS | E | 496 | −16.559 | 19.071 | 45.865 | 1.00 | 30.34 | E | N |
| ATOM | 8369 | C | HIS | E | 496 | −21.580 | 21.989 | 44.665 | 1.00 | 28.36 | E | C |
| ATOM | 8370 | O | HIS | E | 496 | −21.135 | 23.035 | 44.203 | 1.00 | 27.85 | E | O |
| ATOM | 8371 | N | PRO | E | 497 | −22.887 | 21.716 | 44.662 | 1.00 | 27.63 | E | N |
| ATOM | 8372 | CD | PRO | E | 497 | −23.490 | 20.491 | 45.214 | 1.00 | 27.69 | E | C |
| ATOM | 8373 | CA | PRO | E | 497 | −23.902 | 22.610 | 44.097 | 1.00 | 29.03 | E | C |
| ATOM | 8374 | CB | PRO | E | 497 | −25.202 | 21.825 | 44.264 | 1.00 | 28.26 | E | C |
| ATOM | 8375 | CG | PRO | E | 497 | −24.922 | 20.876 | 45.380 | 1.00 | 27.72 | E | C |
| ATOM | 8376 | C | PRO | E | 497 | −24.004 | 24.009 | 44.709 | 1.00 | 29.38 | E | C |
| ATOM | 8377 | O | PRO | E | 497 | −24.063 | 24.999 | 43.978 | 1.00 | 29.37 | E | O |
| ATOM | 8378 | N | GLU | E | 498 | −24.044 | 24.095 | 46.038 | 1.00 | 27.95 | E | N |
| ATOM | 8379 | CA | GLU | E | 498 | −24.163 | 25.389 | 46.707 | 1.00 | 25.80 | E | C |
| ATOM | 8380 | CB | GLU | E | 498 | −24.439 | 25.199 | 48.201 | 1.00 | 27.07 | E | C |
| ATOM | 8381 | CG | GLU | E | 498 | −25.767 | 25.803 | 48.641 | 1.00 | 29.49 | E | C |
| ATOM | 8382 | CD | GLU | E | 498 | −26.140 | 25.473 | 50.084 | 1.00 | 33.63 | E | C |
| ATOM | 8383 | OE1 | GLU | E | 498 | −25.262 | 25.040 | 50.863 | 1.00 | 33.32 | E | O |
| ATOM | 8384 | OE2 | GLU | E | 498 | −27.326 | 25.654 | 50.439 | 1.00 | 34.55 | E | O |
| ATOM | 8385 | C | GLU | E | 498 | −22.936 | 26.263 | 46.513 | 1.00 | 23.58 | E | C |
| ATOM | 8386 | O | GLU | E | 498 | −23.053 | 27.465 | 46.277 | 1.00 | 22.77 | E | O |
| ATOM | 8387 | N | LEU | E | 499 | −21.759 | 25.661 | 46.614 | 1.00 | 23.23 | E | N |
| ATOM | 8388 | CA | LEU | E | 499 | −20.519 | 26.403 | 46.420 | 1.00 | 23.61 | E | C |
| ATOM | 8389 | CB | LEU | E | 499 | −19.310 | 25.526 | 46.772 | 1.00 | 20.27 | E | C |
| ATOM | 8390 | CG | LEU | E | 499 | −17.928 | 26.164 | 46.610 | 1.00 | 19.81 | E | C |
| ATOM | 8391 | CD1 | LEU | E | 499 | −17.894 | 27.526 | 47.292 | 1.00 | 20.20 | E | C |
| ATOM | 8392 | CD2 | LEU | E | 499 | −16.880 | 25.241 | 47.195 | 1.00 | 17.80 | E | C |
| ATOM | 8393 | C | LEU | E | 499 | −20.432 | 26.857 | 44.961 | 1.00 | 23.96 | E | C |
| ATOM | 8394 | O | LEU | E | 499 | −20.046 | 27.991 | 44.678 | 1.00 | 25.57 | E | O |
| ATOM | 8395 | N | SER | E | 500 | −20.799 | 25.965 | 44.043 | 1.00 | 24.17 | E | N |
| ATOM | 8396 | CA | SER | E | 500 | −20.784 | 26.264 | 42.610 | 1.00 | 23.22 | E | C |
| ATOM | 8397 | CB | SER | E | 500 | −21.336 | 25.074 | 41.810 | 1.00 | 22.27 | E | C |
| ATOM | 8398 | OG | SER | E | 500 | −20.397 | 24.014 | 41.751 | 1.00 | 20.95 | E | O |
| ATOM | 8399 | C | SER | E | 500 | −21.633 | 27.502 | 42.323 | 1.00 | 22.43 | E | C |
| ATOM | 8400 | O | SER | E | 500 | −21.225 | 28.394 | 41.578 | 1.00 | 22.98 | E | O |
| ATOM | 8401 | N | VAL | E | 501 | −22.821 | 27.543 | 42.914 | 1.00 | 21.87 | E | N |
| ATOM | 8402 | CA | VAL | E | 501 | −23.732 | 28.668 | 42.733 | 1.00 | 21.64 | E | C |
| ATOM | 8403 | CB | VAL | E | 501 | −25.081 | 28.387 | 43.432 | 1.00 | 20.56 | E | C |
| ATOM | 8404 | CG1 | VAL | E | 501 | −25.867 | 29.679 | 43.623 | 1.00 | 17.84 | E | C |
| ATOM | 8405 | CG2 | VAL | E | 501 | −25.872 | 27.387 | 42.617 | 1.00 | 19.92 | E | C |
| ATOM | 8406 | C | VAL | E | 501 | −23.121 | 29.951 | 43.299 | 1.00 | 22.61 | E | C |
| ATOM | 8407 | O | VAL | E | 501 | −23.155 | 31.005 | 42.663 | 1.00 | 22.01 | E | O |
| ATOM | 8408 | N | PHE | E | 502 | −22.561 | 29.851 | 44.500 | 1.00 | 22.90 | E | N |
| ATOM | 8409 | CA | PHE | E | 502 | −21.946 | 30.993 | 45.165 | 1.00 | 22.35 | E | C |
| ATOM | 8410 | CB | PHE | E | 502 | −21.383 | 30.546 | 46.532 | 1.00 | 21.19 | E | C |
| ATOM | 8411 | CG | PHE | E | 502 | −20.688 | 31.642 | 47.315 | 1.00 | 17.76 | E | C |
| ATOM | 8412 | CD1 | PHE | E | 502 | −21.347 | 32.824 | 47.628 | 1.00 | 17.85 | E | C |
| ATOM | 8413 | CD2 | PHE | E | 502 | −19.383 | 31.470 | 47.758 | 1.00 | 17.69 | E | C |
| ATOM | 8414 | CE1 | PHE | E | 502 | −20.715 | 33.823 | 48.377 | 1.00 | 17.90 | E | C |
| ATOM | 8415 | CE2 | PHE | E | 502 | −18.742 | 32.460 | 48.505 | 1.00 | 19.41 | E | C |
| ATOM | 8416 | CZ | PHE | E | 502 | −19.413 | 33.640 | 48.815 | 1.00 | 17.22 | E | C |
| ATOM | 8417 | C | PHE | E | 502 | −20.837 | 31.573 | 44.283 | 1.00 | 20.85 | E | C |
| ATOM | 8418 | O | PHE | E | 502 | −20.774 | 32.785 | 44.059 | 1.00 | 19.93 | E | O |
| ATOM | 8419 | N | LEU | E | 503 | −19.974 | 30.698 | 43.776 | 1.00 | 20.20 | E | N |
| ATOM | 8420 | CA | LEU | E | 503 | −18.857 | 31.115 | 42.937 | 1.00 | 19.31 | E | C |
| ATOM | 8421 | CB | LEU | E | 503 | −18.036 | 29.897 | 42.531 | 1.00 | 17.77 | E | C |
| ATOM | 8422 | CG | LEU | E | 503 | −17.160 | 29.325 | 43.643 | 1.00 | 18.61 | E | C |
| ATOM | 8423 | CD1 | LEU | E | 503 | −16.459 | 28.074 | 43.142 | 1.00 | 17.00 | E | C |
| ATOM | 8424 | CD2 | LEU | E | 503 | −16.143 | 30.370 | 44.091 | 1.00 | 17.59 | E | C |
| ATOM | 8425 | C | LEU | E | 503 | −19.279 | 31.896 | 41.694 | 1.00 | 19.85 | E | C |
| ATOM | 8426 | O | LEU | E | 503 | −18.474 | 32.627 | 41.120 | 1.00 | 22.16 | E | O |
| ATOM | 8427 | N | LYS | E | 504 | −20.529 | 31.740 | 41.276 | 1.00 | 18.96 | E | N |
| ATOM | 8428 | CA | LYS | E | 504 | −21.031 | 32.462 | 40.113 | 1.00 | 21.69 | E | C |
| ATOM | 8429 | CB | LYS | E | 504 | −22.290 | 31.792 | 39.558 | 1.00 | 21.09 | E | C |
| ATOM | 8430 | CG | LYS | E | 504 | −22.018 | 30.535 | 38.765 | 1.00 | 22.18 | E | C |
| ATOM | 8431 | CD | LYS | E | 504 | −23.308 | 29.826 | 38.405 | 1.00 | 25.33 | E | C |
| ATOM | 8432 | CE | LYS | E | 504 | −24.166 | 30.660 | 37.468 | 1.00 | 25.58 | E | C |
| ATOM | 8433 | NZ | LYS | E | 504 | −25.555 | 30.122 | 37.375 | 1.00 | 28.82 | E | N |
| ATOM | 8434 | C | LYS | E | 504 | −21.367 | 33.896 | 40.509 | 1.00 | 22.72 | E | C |
| ATOM | 8435 | O | LYS | E | 504 | −21.589 | 34.746 | 39.645 | 1.00 | 24.10 | E | O |
| ATOM | 8436 | N | HIS | E | 505 | −21.410 | 34.153 | 41.818 | 1.00 | 20.94 | E | N |
| ATOM | 8437 | CA | HIS | E | 505 | −21.728 | 35.478 | 42.343 | 1.00 | 18.16 | E | C |
| ATOM | 8438 | CB | HIS | E | 505 | −22.710 | 35.359 | 43.512 | 1.00 | 17.82 | E | C |
| ATOM | 8439 | CG | HIS | E | 505 | −24.094 | 34.946 | 43.106 | 1.00 | 19.58 | E | C |
| ATOM | 8440 | CD2 | HIS | E | 505 | −24.600 | 33.738 | 42.758 | 1.00 | 20.64 | E | C |
| ATOM | 8441 | ND1 | HIS | E | 505 | −25.154 | 35.828 | 43.070 | 1.00 | 20.64 | E | N |
| ATOM | 8442 | CE1 | HIS | E | 505 | −26.252 | 35.183 | 42.718 | 1.00 | 21.17 | E | C |
| ATOM | 8443 | NE2 | HIS | E | 505 | −25.944 | 33.913 | 42.523 | 1.00 | 21.59 | E | N |
| ATOM | 8444 | C | HIS | E | 505 | −20.485 | 36.237 | 42.804 | 1.00 | 16.57 | E | C |
| ATOM | 8445 | O | HIS | E | 505 | −20.580 | 37.398 | 43.195 | 1.00 | 16.25 | E | O |
| ATOM | 8446 | N | ILE | E | 506 | −19.328 | 35.580 | 42.760 | 1.00 | 15.59 | E | N |
| ATOM | 8447 | CA | ILE | E | 506 | −18.064 | 36.193 | 43.165 | 1.00 | 15.08 | E | C |
| ATOM | 8448 | CB | ILE | E | 506 | −17.130 | 35.177 | 43.875 | 1.00 | 13.07 | E | C |
| ATOM | 8449 | CG2 | ILE | E | 506 | −15.774 | 35.809 | 44.126 | 1.00 | 11.18 | E | C |
| ATOM | 8450 | CG1 | ILE | E | 506 | −17.749 | 34.713 | 45.202 | 1.00 | 14.62 | E | C |
| ATOM | 8451 | CD1 | ILE | E | 506 | −18.362 | 35.831 | 46.050 | 1.00 | 14.23 | E | C |
| ATOM | 8452 | C | ILE | E | 506 | −17.337 | 36.737 | 41.937 | 1.00 | 18.44 | E | C |
| ATOM | 8453 | O | ILE | E | 506 | −17.037 | 35.988 | 40.997 | 1.00 | 18.74 | E | O |
| ATOM | 8454 | N | THR | E | 507 | −17.039 | 38.035 | 41.959 | 1.00 | 17.95 | E | N |
| ATOM | 8455 | CA | THR | E | 507 | −16.373 | 38.695 | 40.845 | 1.00 | 17.25 | E | C |
| ATOM | 8456 | CB | THR | E | 507 | −16.914 | 40.130 | 40.660 | 1.00 | 16.84 | E | C |
| ATOM | 8457 | OG1 | THR | E | 507 | −16.415 | 40.977 | 41.705 | 1.00 | 18.13 | E | O |
| ATOM | 8458 | CG2 | THR | E | 507 | −18.437 | 40.130 | 40.689 | 1.00 | 14.14 | E | C |
| ATOM | 8459 | C | THR | E | 507 | −14.849 | 38.753 | 40.938 | 1.00 | 17.99 | E | C |
| ATOM | 8460 | O | THR | E | 507 | −14.168 | 38.796 | 39.911 | 1.00 | 17.95 | E | O |
| ATOM | 8461 | N | GLY | E | 508 | −14.307 | 38.751 | 42.156 | 1.00 | 17.94 | E | N |
| ATOM | 8462 | CA | GLY | E | 508 | −12.861 | 38.810 | 42.303 | 1.00 | 16.46 | E | C |
| ATOM | 8463 | C | GLY | E | 508 | −12.335 | 38.590 | 43.708 | 1.00 | 17.39 | E | C |
| ATOM | 8464 | O | GLY | E | 508 | −13.108 | 38.364 | 44.641 | 1.00 | 17.40 | E | O |
| ATOM | 8465 | N | PHE | E | 509 | −11.012 | 38.668 | 43.853 | 1.00 | 17.84 | E | N |
| ATOM | 8466 | CA | PHE | E | 509 | −10.337 | 38.474 | 45.139 | 1.00 | 18.54 | E | C |
| ATOM | 8467 | CB | PHE | E | 509 | −9.339 | 37.316 | 45.049 | 1.00 | 19.21 | E | C |
| ATOM | 8468 | CG | PHE | E | 509 | −9.981 | 35.968 | 44.953 | 1.00 | 20.98 | E | C |
| ATOM | 8469 | CD1 | PHE | E | 509 | −10.151 | 35.185 | 46.087 | 1.00 | 21.32 | E | C |
| ATOM | 8470 | CD2 | PHE | E | 509 | −10.413 | 35.475 | 43.724 | 1.00 | 21.48 | E | C |
| ATOM | 8471 | CE1 | PHE | E | 509 | −10.742 | 33.929 | 46.004 | 1.00 | 22.13 | E | C |
| ATOM | 8472 | CE2 | PHE | E | 509 | −11.006 | 34.220 | 43.629 | 1.00 | 22.38 | E | C |
| ATOM | 8473 | CZ | PHE | E | 509 | −11.171 | 33.443 | 44.774 | 1.00 | 22.18 | E | C |
| ATOM | 8474 | C | PHE | E | 509 | −9.579 | 39.715 | 45.612 | 1.00 | 18.57 | E | C |
| ATOM | 8475 | O | PHE | E | 509 | −8.932 | 40.400 | 44.812 | 1.00 | 17.83 | E | O |
| ATOM | 8476 | N | ASP | E | 510 | −9.655 | 39.981 | 46.917 | 1.00 | 17.12 | E | N |
| ATOM | 8477 | CA | ASP | E | 510 | −8.970 | 41.113 | 47.530 | 1.00 | 15.78 | E | C |
| ATOM | 8478 | CB | ASP | E | 510 | −9.980 | 42.028 | 48.230 | 1.00 | 13.63 | E | C |
| ATOM | 8479 | CG | ASP | E | 510 | −9.486 | 43.461 | 48.371 | 1.00 | 12.35 | E | C |
| ATOM | 8480 | OD1 | ASP | E | 510 | −8.266 | 43.680 | 48.482 | 1.00 | 13.00 | E | O |
| ATOM | 8481 | OD2 | ASP | E | 510 | −10.330 | 44.379 | 48.373 | 1.00 | 15.04 | E | O |
| ATOM | 8482 | C | ASP | E | 510 | −7.969 | 40.562 | 48.548 | 1.00 | 17.25 | E | C |
| ATOM | 8483 | O | ASP | E | 510 | −8.073 | 39.408 | 48.970 | 1.00 | 15.52 | E | O |
| ATOM | 8484 | N | SER | E | 511 | −6.991 | 41.382 | 48.919 | 1.00 | 18.67 | E | N |
| ATOM | 8485 | CA | SER | E | 511 | −5.977 | 41.002 | 49.901 | 1.00 | 19.47 | E | C |
| ATOM | 8486 | CB | SER | E | 511 | −4.638 | 40.764 | 49.214 | 1.00 | 20.09 | E | C |
| ATOM | 8487 | OG | SER | E | 511 | −3.619 | 40.538 | 50.168 | 1.00 | 18.85 | E | O |
| ATOM | 8488 | C | SER | E | 511 | −5.856 | 42.163 | 50.887 | 1.00 | 19.88 | E | C |
| ATOM | 8489 | O | SER | E | 511 | −5.548 | 43.285 | 50.486 | 1.00 | 19.34 | E | O |
| ATOM | 8490 | N | VAL | E | 512 | −6.090 | 41.895 | 52.171 | 1.00 | 20.43 | E | N |
| ATOM | 8491 | CA | VAL | E | 512 | −6.044 | 42.952 | 53.182 | 1.00 | 19.45 | E | C |
| ATOM | 8492 | CB | VAL | E | 512 | −7.461 | 43.255 | 53.708 | 1.00 | 18.41 | E | C |
| ATOM | 8493 | CG1 | VAL | E | 512 | −8.359 | 43.701 | 52.566 | 1.00 | 20.59 | E | C |
| ATOM | 8494 | CG2 | VAL | E | 512 | −8.035 | 42.025 | 54.369 | 1.00 | 18.12 | E | C |
| ATOM | 8495 | C | VAL | E | 512 | −5.135 | 42.711 | 54.394 | 1.00 | 20.74 | E | C |
| ATOM | 8496 | O | VAL | E | 512 | −4.873 | 41.574 | 54.787 | 1.00 | 17.77 | E | O |
| ATOM | 8497 | N | ASP | E | 513 | −4.673 | 43.813 | 54.981 | 1.00 | 21.81 | E | N |
| ATOM | 8498 | CA | ASP | E | 513 | −3.804 | 43.808 | 56.156 | 1.00 | 23.12 | E | C |
| ATOM | 8499 | CB | ASP | E | 513 | −2.620 | 42.851 | 55.960 | 1.00 | 24.25 | E | C |
| ATOM | 8500 | CG | ASP | E | 513 | −1.889 | 42.528 | 57.275 | 1.00 | 27.36 | E | C |
| ATOM | 8501 | OD1 | ASP | E | 513 | −2.380 | 42.913 | 58.360 | 1.00 | 25.37 | E | O |
| ATOM | 8502 | OD2 | ASP | E | 513 | −0.817 | 41.885 | 57.225 | 1.00 | 27.92 | E | O |
| ATOM | 8503 | C | ASP | E | 513 | −3.279 | 45.224 | 56.364 | 1.00 | 23.97 | E | C |
| ATOM | 8504 | O | ASP | E | 513 | −3.558 | 46.114 | 55.568 | 1.00 | 24.95 | E | O |
| ATOM | 8505 | N | ASP | E | 514 | −2.533 | 45.436 | 57.441 | 1.00 | 24.81 | E | N |
| ATOM | 8506 | CA | ASP | E | 514 | −1.950 | 46.743 | 57.719 | 1.00 | 25.33 | E | C |
| ATOM | 8507 | CB | ASP | E | 514 | −1.476 | 46.820 | 59.173 | 1.00 | 27.06 | E | C |
| ATOM | 8508 | CG | ASP | E | 514 | −0.901 | 48.178 | 59.528 | 1.00 | 28.76 | E | C |
| ATOM | 8509 | OD1 | ASP | E | 514 | −0.703 | 49.008 | 58.613 | 1.00 | 28.57 | E | O |
| ATOM | 8510 | OD2 | ASP | E | 514 | −0.648 | 48.418 | 60.725 | 1.00 | 30.06 | E | O |
| ATOM | 8511 | C | ASP | E | 514 | −0.757 | 46.856 | 56.783 | 1.00 | 24.72 | E | C |
| ATOM | 8512 | O | ASP | E | 514 | 0.296 | 46.275 | 57.038 | 1.00 | 25.62 | E | O |
| ATOM | 8513 | N | GLU | E | 515 | −0.926 | 47.601 | 55.696 | 1.00 | 24.65 | E | N |
| ATOM | 8514 | CA | GLU | E | 515 | 0.133 | 47.749 | 54.706 | 1.00 | 23.87 | E | C |
| ATOM | 8515 | CB | GLU | E | 515 | −0.393 | 48.480 | 53.471 | 1.00 | 21.61 | E | C |
| ATOM | 8516 | CG | GLU | E | 515 | −0.091 | 47.746 | 52.176 | 1.00 | 19.13 | E | C |
| ATOM | 8517 | CD | GLU | E | 515 | −0.391 | 48.582 | 50.951 | 1.00 | 17.15 | E | C |
| ATOM | 8518 | OE1 | GLU | E | 515 | −1.436 | 49.264 | 50.937 | 1.00 | 15.87 | E | O |
| ATOM | 8519 | OE2 | GLU | E | 515 | 0.420 | 48.555 | 50.004 | 1.00 | 15.70 | E | O |
| ATOM | 8520 | C | GLU | E | 515 | 1.383 | 48.438 | 55.201 | 1.00 | 24.30 | E | C |
| ATOM | 8521 | O | GLU | E | 515 | 2.443 | 48.302 | 54.594 | 1.00 | 24.57 | E | O |
| ATOM | 8522 | N | SER | E | 516 | 1.266 | 49.177 | 56.298 | 1.00 | 26.32 | E | N |
| ATOM | 8523 | CA | SER | E | 516 | 2.411 | 49.886 | 56.856 | 1.00 | 29.08 | E | C |
| ATOM | 8524 | CB | SER | E | 516 | 1.947 | 51.019 | 57.771 | 1.00 | 27.76 | E | C |
| ATOM | 8525 | OG | SER | E | 516 | 1.483 | 50.509 | 59.006 | 1.00 | 28.76 | E | O |
| ATOM | 8526 | C | SER | E | 516 | 3.322 | 48.950 | 57.634 | 1.00 | 30.89 | E | C |
| ATOM | 8527 | O | SER | E | 516 | 4.430 | 49.322 | 57.997 | 1.00 | 31.28 | E | O |
| ATOM | 8528 | N | LYS | E | 517 | 2.853 | 47.736 | 57.889 | 1.00 | 34.55 | E | N |
| ATOM | 8529 | CA | LYS | E | 517 | 3.642 | 46.758 | 58.622 | 1.00 | 38.82 | E | C |
| ATOM | 8530 | CB | LYS | E | 517 | 2.894 | 45.430 | 58.706 | 1.00 | 37.97 | E | C |
| ATOM | 8531 | CG | LYS | E | 517 | 2.632 | 44.954 | 60.120 | 1.00 | 37.89 | E | C |
| ATOM | 8532 | CD | LYS | E | 517 | 1.245 | 44.351 | 60.267 | 1.00 | 38.20 | E | C |
| ATOM | 8533 | CE | LYS | E | 517 | 1.033 | 43.180 | 59.315 | 1.00 | 37.89 | E | C |
| ATOM | 8534 | NZ | LYS | E | 517 | 1.166 | 41.858 | 59.986 | 1.00 | 39.94 | E | N |
| ATOM | 8535 | C | LYS | E | 517 | 4.985 | 46.542 | 57.947 | 1.00 | 43.91 | E | C |
| ATOM | 8536 | O | LYS | E | 517 | 5.138 | 46.771 | 56.748 | 1.00 | 44.80 | E | O |
| ATOM | 8537 | N | HIS | E | 518 | 5.956 | 46.100 | 58.737 | 1.00 | 49.52 | E | N |
| ATOM | 8538 | CA | HIS | E | 518 | 7.318 | 45.838 | 58.276 | 1.00 | 55.01 | E | C |
| ATOM | 8539 | CB | HIS | E | 518 | 8.271 | 45.977 | 59.453 | 1.00 | 60.72 | E | C |
| ATOM | 8540 | CG | HIS | E | 518 | 7.875 | 45.133 | 60.625 | 1.00 | 67.20 | E | C |
| ATOM | 8541 | CD2 | HIS | E | 518 | 6.930 | 45.321 | 61.579 | 1.00 | 69.31 | E | C |
| ATOM | 8542 | ND1 | HIS | E | 518 | 8.418 | 43.887 | 60.863 | 1.00 | 69.51 | E | N |
| ATOM | 8543 | CE1 | HIS | E | 518 | 7.824 | 43.344 | 61.912 | 1.00 | 71.60 | E | C |
| ATOM | 8544 | NE2 | HIS | E | 518 | 6.918 | 44.194 | 62.365 | 1.00 | 71.71 | E | N |
| ATOM | 8545 | C | HIS | E | 518 | 7.398 | 44.405 | 57.765 | 1.00 | 55.83 | E | C |
| ATOM | 8546 | O | HIS | E | 518 | 6.549 | 43.577 | 58.096 | 1.00 | 57.01 | E | O |
| ATOM | 8547 | N | SER | E | 519 | 8.426 | 44.104 | 56.978 | 1.00 | 55.73 | E | N |
| ATOM | 8548 | CA | SER | E | 519 | 8.601 | 42.751 | 56.457 | 1.00 | 55.29 | E | C |
| ATOM | 8549 | CB | SER | E | 519 | 8.208 | 42.687 | 54.978 | 1.00 | 55.33 | E | C |
| ATOM | 8550 | OG | SER | E | 519 | 8.358 | 41.368 | 54.482 | 1.00 | 53.69 | E | O |
| ATOM | 8551 | C | SER | E | 519 | 10.044 | 42.288 | 56.621 | 1.00 | 55.15 | E | C |
| ATOM | 8552 | O | SER | E | 519 | 10.312 | 41.281 | 57.280 | 1.00 | 53.94 | E | O |
| ATOM | 8553 | N | GLY | E | 520 | 10.966 | 43.032 | 56.015 | 1.00 | 54.90 | E | N |
| ATOM | 8554 | CA | GLY | E | 520 | 12.373 | 42.690 | 56.098 | 1.00 | 55.14 | E | C |
| ATOM | 8555 | C | GLY | E | 520 | 12.821 | 41.719 | 55.020 | 1.00 | 55.03 | E | C |
| ATOM | 8556 | O | GLY | E | 520 | 13.952 | 41.797 | 54.539 | 1.00 | 55.87 | E | O |
| ATOM | 8557 | N | HIS | E | 521 | 11.933 | 40.806 | 54.638 | 1.00 | 55.00 | E | N |
| ATOM | 8558 | CA | HIS | E | 521 | 12.237 | 39.804 | 53.618 | 1.00 | 54.65 | E | C |
| ATOM | 8559 | CB | HIS | E | 521 | 12.087 | 38.398 | 54.208 | 1.00 | 56.35 | E | C |
| ATOM | 8560 | CG | HIS | E | 521 | 10.851 | 38.215 | 55.039 | 1.00 | 59.11 | E | C |
| ATOM | 8561 | CD2 | HIS | E | 521 | 9.537 | 38.280 | 54.715 | 1.00 | 59.41 | E | C |
| ATOM | 8562 | ND1 | HIS | E | 521 | 10.897 | 37.924 | 56.388 | 1.00 | 60.57 | E | N |
| ATOM | 8563 | CE1 | HIS | E | 521 | 9.666 | 37.819 | 56.857 | 1.00 | 60.83 | E | C |
| ATOM | 8564 | NE2 | HIS | E | 521 | 8.822 | 38.031 | 55.862 | 1.00 | 60.64 | E | N |
| ATOM | 8565 | C | HIS | E | 521 | 11.313 | 39.941 | 52.413 | 1.00 | 53.15 | E | C |
| ATOM | 8566 | O | HIS | E | 521 | 10.095 | 39.860 | 52.552 | 1.00 | 54.64 | E | O |
| ATOM | 8567 | N | MET | E | 522 | 11.877 | 40.148 | 51.228 | 1.00 | 50.77 | E | N |
| ATOM | 8568 | CA | MET | E | 522 | 11.036 | 40.269 | 50.043 | 1.00 | 49.47 | E | C |
| ATOM | 8569 | CB | MET | E | 522 | 11.357 | 41.539 | 49.259 | 1.00 | 49.89 | E | C |
| ATOM | 8570 | CG | MET | E | 522 | 10.112 | 42.157 | 48.636 | 1.00 | 52.15 | E | C |
| ATOM | 8571 | SD | MET | E | 522 | 10.359 | 42.748 | 46.963 | 1.00 | 53.18 | E | S |
| ATOM | 8572 | CE | MET | E | 522 | 11.529 | 44.092 | 47.270 | 1.00 | 52.39 | E | C |
| ATOM | 8573 | C | MET | E | 522 | 11.147 | 39.069 | 49.119 | 1.00 | 46.43 | E | C |
| ATOM | 8574 | O | MET | E | 522 | 12.151 | 38.357 | 49.122 | 1.00 | 46.65 | E | O |
| ATOM | 8575 | N | PHE | E | 523 | 10.100 | 38.854 | 48.330 | 1.00 | 42.24 | E | N |
| ATOM | 8576 | CA | PHE | E | 523 | 10.047 | 37.741 | 47.391 | 1.00 | 38.84 | E | C |
| ATOM | 8577 | CB | PHE | E | 523 | 8.835 | 37.895 | 46.475 | 1.00 | 35.76 | E | C |
| ATOM | 8578 | CG | PHE | E | 523 | 8.457 | 36.635 | 45.763 | 1.00 | 33.75 | E | C |
| ATOM | 8579 | CD1 | PHE | E | 523 | 8.332 | 35.438 | 46.460 | 1.00 | 32.09 | E | C |
| ATOM | 8580 | CD2 | PHE | E | 523 | 8.214 | 36.643 | 44.394 | 1.00 | 33.01 | E | C |
| ATOM | 8581 | CE1 | PHE | E | 523 | 7.970 | 34.271 | 45.803 | 1.00 | 31.84 | E | C |
| ATOM | 8582 | CE2 | PHE | E | 523 | 7.851 | 35.479 | 43.729 | 1.00 | 30.41 | E | C |
| ATOM | 8583 | CZ | PHE | E | 523 | 7.728 | 34.292 | 44.432 | 1.00 | 30.03 | E | C |
| ATOM | 8584 | C | PHE | E | 523 | 11.313 | 37.634 | 46.548 | 1.00 | 37.84 | E | C |
| ATOM | 8585 | O | PHE | E | 523 | 11.776 | 38.621 | 45.981 | 1.00 | 37.97 | E | O |
| ATOM | 8586 | N | SER | E | 524 | 11.869 | 36.430 | 46.467 | 1.00 | 37.08 | E | N |
| ATOM | 8587 | CA | SER | E | 524 | 13.077 | 36.205 | 45.691 | 1.00 | 37.63 | E | C |
| ATOM | 8588 | CB | SER | E | 524 | 14.299 | 36.745 | 46.438 | 1.00 | 37.27 | E | C |
| ATOM | 8589 | OG | SER | E | 524 | 15.075 | 35.690 | 46.978 | 1.00 | 37.19 | E | O |
| ATOM | 8590 | C | SER | E | 524 | 13.286 | 34.731 | 45.383 | 1.00 | 38.94 | E | C |
| ATOM | 8591 | O | SER | E | 524 | 12.509 | 33.878 | 45.804 | 1.00 | 39.01 | E | O |
| ATOM | 8592 | N | SER | E | 525 | 14.350 | 34.446 | 44.643 | 1.00 | 39.88 | E | N |
| ATOM | 8593 | CA | SER | E | 525 | 14.693 | 33.084 | 44.259 | 1.00 | 41.76 | E | C |
| ATOM | 8594 | CB | SER | E | 525 | 15.921 | 33.106 | 43.353 | 1.00 | 41.67 | E | C |
| ATOM | 8595 | OG | SER | E | 525 | 15.670 | 32.400 | 42.156 | 1.00 | 45.24 | E | O |
| ATOM | 8596 | C | SER | E | 525 | 14.981 | 32.194 | 45.464 | 1.00 | 42.17 | E | C |
| ATOM | 8597 | O | SER | E | 525 | 14.694 | 30.995 | 45.447 | 1.00 | 41.67 | E | O |
| ATOM | 8598 | N | LYS | E | 526 | 15.555 | 32.788 | 46.503 | 1.00 | 42.43 | E | N |
| ATOM | 8599 | CA | LYS | E | 526 | 15.907 | 32.054 | 47.712 | 1.00 | 41.95 | E | C |
| ATOM | 8600 | CB | LYS | E | 526 | 16.975 | 32.824 | 48.496 | 1.00 | 45.04 | E | C |
| ATOM | 8601 | CG | LYS | E | 526 | 18.019 | 33.509 | 47.632 | 1.00 | 47.56 | E | C |
| ATOM | 8602 | CD | LYS | E | 526 | 19.410 | 32.957 | 47.912 | 1.00 | 51.62 | E | C |
| ATOM | 8603 | CE | LYS | E | 526 | 20.483 | 34.024 | 47.706 | 1.00 | 53.86 | E | C |
| ATOM | 8604 | NZ | LYS | E | 526 | 21.555 | 33.967 | 48.746 | 1.00 | 55.30 | E | N |
| ATOM | 8605 | C | LYS | E | 526 | 14.709 | 31.785 | 48.620 | 1.00 | 40.49 | E | C |
| ATOM | 8606 | O | LYS | E | 526 | 14.758 | 30.899 | 49.473 | 1.00 | 39.67 | E | O |
| ATOM | 8607 | N | SER | E | 527 | 13.637 | 32.547 | 48.438 | 1.00 | 37.43 | E | N |
| ATOM | 8608 | CA | SER | E | 527 | 12.445 | 32.379 | 49.258 | 1.00 | 35.52 | E | C |
| ATOM | 8609 | CB | SER | E | 527 | 11.339 | 33.331 | 48.784 | 1.00 | 34.53 | E | C |
| ATOM | 8610 | OG | SER | E | 527 | 11.745 | 34.682 | 48.904 | 1.00 | 32.48 | E | O |
| ATOM | 8611 | C | SER | E | 527 | 11.915 | 30.941 | 49.262 | 1.00 | 34.94 | E | C |
| ATOM | 8612 | O | SER | E | 527 | 11.729 | 30.332 | 48.209 | 1.00 | 35.60 | E | O |
| ATOM | 8613 | N | PRO | E | 528 | 11.685 | 30.373 | 50.460 | 1.00 | 34.34 | E | N |
| ATOM | 8614 | CD | PRO | E | 528 | 11.924 | 30.963 | 51.790 | 1.00 | 33.29 | E | C |
| ATOM | 8615 | CA | PRO | E | 528 | 11.169 | 29.002 | 50.551 | 1.00 | 32.88 | E | C |
| ATOM | 8616 | CB | PRO | E | 528 | 11.169 | 28.709 | 52.051 | 1.00 | 32.03 | E | C |
| ATOM | 8617 | CG | PRO | E | 528 | 11.176 | 30.043 | 52.711 | 1.00 | 32.27 | E | C |
| ATOM | 8618 | C | PRO | E | 528 | 9.770 | 28.882 | 49.955 | 1.00 | 32.91 | E | C |
| ATOM | 8619 | O | PRO | E | 528 | 8.997 | 29.840 | 49.972 | 1.00 | 33.99 | E | O |
| ATOM | 8620 | N | LYS | E | 529 | 9.449 | 27.709 | 49.418 | 1.00 | 32.55 | E | N |
| ATOM | 8621 | CA | LYS | E | 529 | 8.130 | 27.479 | 48.843 | 1.00 | 32.59 | E | C |
| ATOM | 8622 | CB | LYS | E | 529 | 8.079 | 26.117 | 48.152 | 1.00 | 32.96 | E | C |
| ATOM | 8623 | CG | LYS | E | 529 | 9.230 | 25.872 | 47.191 | 1.00 | 32.34 | E | C |
| ATOM | 8624 | CD | LYS | E | 529 | 9.057 | 26.673 | 45.915 | 1.00 | 32.59 | E | C |
| ATOM | 8625 | CE | LYS | E | 529 | 10.283 | 27.526 | 45.629 | 1.00 | 34.22 | E | C |
| ATOM | 8626 | NZ | LYS | E | 529 | 10.932 | 27.168 | 44.335 | 1.00 | 31.77 | E | N |
| ATOM | 8627 | C | LYS | E | 529 | 7.148 | 27.507 | 50.005 | 1.00 | 32.33 | E | C |
| ATOM | 8628 | O | LYS | E | 529 | 7.556 | 27.361 | 51.154 | 1.00 | 32.47 | E | O |
| ATOM | 8629 | N | PRO | E | 530 | 5.846 | 27.702 | 49.724 | 1.00 | 31.90 | E | N |
| ATOM | 8630 | CD | PRO | E | 530 | 5.267 | 27.911 | 48.388 | 1.00 | 30.74 | E | C |
| ATOM | 8631 | CA | PRO | E | 530 | 4.814 | 27.751 | 50.768 | 1.00 | 31.72 | E | C |
| ATOM | 8632 | CB | PRO | E | 530 | 3.512 | 27.816 | 49.974 | 1.00 | 30.02 | E | C |
| ATOM | 8633 | CG | PRO | E | 530 | 3.897 | 28.448 | 48.700 | 1.00 | 29.33 | E | C |
| ATOM | 8634 | C | PRO | E | 530 | 4.826 | 26.582 | 51.759 | 1.00 | 33.02 | E | C |
| ATOM | 8635 | O | PRO | E | 530 | 4.683 | 26.776 | 52.970 | 1.00 | 32.92 | E | O |
| ATOM | 8636 | N | GLN | E | 531 | 4.988 | 25.369 | 51.242 | 1.00 | 33.06 | E | N |
| ATOM | 8637 | CA | GLN | E | 531 | 5.013 | 24.184 | 52.090 | 1.00 | 33.25 | E | C |
| ATOM | 8638 | CB | GLN | E | 531 | 4.937 | 22.918 | 51.231 | 1.00 | 34.53 | E | C |
| ATOM | 8639 | CG | GLN | E | 531 | 6.195 | 22.646 | 50.406 | 1.00 | 36.83 | E | C |
| ATOM | 8640 | CD | GLN | E | 531 | 6.112 | 23.189 | 48.982 | 1.00 | 38.17 | E | C |
| ATOM | 8641 | OE1 | GLN | E | 531 | 5.300 | 24.069 | 48.680 | 1.00 | 37.95 | E | O |
| ATOM | 8642 | NE2 | GLN | E | 531 | 6.961 | 22.664 | 48.101 | 1.00 | 38.97 | E | N |
| ATOM | 8643 | C | GLN | E | 531 | 6.279 | 24.160 | 52.938 | 1.00 | 32.79 | E | C |
| ATOM | 8644 | O | GLN | E | 531 | 6.318 | 23.516 | 53.980 | 1.00 | 32.80 | E | O |
| ATOM | 8645 | N | GLU | E | 532 | 7.312 | 24.861 | 52.487 | 1.00 | 31.66 | E | N |
| ATOM | 8646 | CA | GLU | E | 532 | 8.566 | 24.916 | 53.221 | 1.00 | 32.50 | E | C |
| ATOM | 8647 | CB | GLU | E | 532 | 9.745 | 24.986 | 52.251 | 1.00 | 36.25 | E | C |
| ATOM | 8648 | CG | GLU | E | 532 | 9.974 | 23.710 | 51.455 | 1.00 | 41.58 | E | C |
| ATOM | 8649 | CD | GLU | E | 532 | 10.678 | 23.968 | 50.127 | 1.00 | 45.51 | E | C |
| ATOM | 8650 | OE1 | GLU | E | 532 | 11.175 | 25.100 | 49.922 | 1.00 | 47.34 | E | O |
| ATOM | 8651 | OE2 | GLU | E | 532 | 10.733 | 23.038 | 49.287 | 1.00 | 48.00 | E | O |
| ATOM | 8652 | C | GLU | E | 532 | 8.604 | 26.121 | 54.157 | 1.00 | 32.65 | E | C |
| ATOM | 8653 | O | GLU | E | 532 | 9.552 | 26.290 | 54.921 | 1.00 | 32.91 | E | O |
| ATOM | 8654 | N | TRP | E | 533 | 7.578 | 26.966 | 54.085 | 1.00 | 31.22 | E | N |
| ATOM | 8655 | CA | TRP | E | 533 | 7.497 | 28.148 | 54.939 | 1.00 | 29.02 | E | C |
| ATOM | 8656 | CB | TRP | E | 533 | 6.710 | 29.265 | 54.242 | 1.00 | 27.34 | E | C |
| ATOM | 8657 | CG | TRP | E | 533 | 6.802 | 30.591 | 54.946 | 1.00 | 26.65 | E | C |
| ATOM | 8658 | CD2 | TRP | E | 533 | 7.569 | 31.735 | 54.534 | 1.00 | 25.73 | E | C |
| ATOM | 8659 | CE2 | TRP | E | 533 | 7.388 | 32.735 | 55.517 | 1.00 | 24.64 | E | C |
| ATOM | 8660 | CE3 | TRP | E | 533 | 8.392 | 32.010 | 53.429 | 1.00 | 24.67 | E | C |
| ATOM | 8661 | CD1 | TRP | E | 533 | 6.204 | 30.938 | 56.125 | 1.00 | 25.27 | E | C |
| ATOM | 8662 | NE1 | TRP | E | 533 | 6.552 | 32.221 | 56.475 | 1.00 | 24.38 | E | N |
| ATOM | 8663 | CZ2 | TRP | E | 533 | 7.999 | 33.991 | 55.432 | 1.00 | 24.47 | E | C |
| ATOM | 8664 | CZ3 | TRP | E | 533 | 9.002 | 33.262 | 53.342 | 1.00 | 23.97 | E | C |
| ATOM | 8665 | CH2 | TRP | E | 533 | 8.800 | 34.236 | 54.341 | 1.00 | 26.07 | E | C |
| ATOM | 8666 | C | TRP | E | 533 | 6.781 | 27.721 | 56.213 | 1.00 | 29.24 | E | C |
| ATOM | 8667 | O | TRP | E | 533 | 5.560 | 27.841 | 56.329 | 1.00 | 28.97 | E | O |
| ATOM | 8668 | N | THR | E | 534 | 7.551 | 27.210 | 57.165 | 1.00 | 29.79 | E | N |
| ATOM | 8669 | CA | THR | E | 534 | 7.002 | 26.740 | 58.433 | 1.00 | 30.77 | E | C |
| ATOM | 8670 | CB | THR | E | 534 | 7.574 | 25.359 | 58.783 | 1.00 | 30.41 | E | C |
| ATOM | 8671 | OG1 | THR | E | 534 | 9.002 | 25.443 | 58.833 | 1.00 | 33.89 | E | O |
| ATOM | 8672 | CG2 | THR | E | 534 | 7.184 | 24.336 | 57.729 | 1.00 | 29.60 | E | C |
| ATOM | 8673 | C | THR | E | 534 | 7.271 | 27.688 | 59.609 | 1.00 | 30.35 | E | C |
| ATOM | 8674 | O | THR | E | 534 | 6.699 | 27.520 | 60.685 | 1.00 | 31.33 | E | O |
| ATOM | 8675 | N | LEU | E | 535 | 8.138 | 28.677 | 59.407 | 1.00 | 31.30 | E | N |
| ATOM | 8676 | CA | LEU | E | 535 | 8.455 | 29.632 | 60.461 | 1.00 | 32.41 | E | C |
| ATOM | 8677 | CB | LEU | E | 535 | 9.624 | 30.531 | 60.044 | 1.00 | 33.18 | E | C |
| ATOM | 8678 | CG | LEU | E | 535 | 9.507 | 31.287 | 58.719 | 1.00 | 36.91 | E | C |
| ATOM | 8679 | CD1 | LEU | E | 535 | 10.261 | 32.596 | 58.825 | 1.00 | 35.37 | E | C |
| ATOM | 8680 | CD2 | LEU | E | 535 | 10.074 | 30.444 | 57.573 | 1.00 | 39.18 | E | C |
| ATOM | 8681 | C | LEU | E | 535 | 7.228 | 30.472 | 60.786 | 1.00 | 34.20 | E | C |
| ATOM | 8682 | O | LEU | E | 535 | 6.222 | 30.416 | 60.083 | 1.00 | 35.68 | E | O |
| ATOM | 8683 | N | GLU | E | 536 | 7.309 | 31.252 | 61.855 | 1.00 | 34.84 | E | N |
| ATOM | 8684 | CA | GLU | E | 536 | 6.179 | 32.065 | 62.277 | 1.00 | 36.04 | E | C |
| ATOM | 8685 | CB | GLU | E | 536 | 6.256 | 32.314 | 63.781 | 1.00 | 39.97 | E | C |
| ATOM | 8686 | CG | GLU | E | 536 | 4.944 | 32.091 | 64.500 | 1.00 | 45.13 | E | C |
| ATOM | 8687 | CD | GLU | E | 536 | 5.089 | 32.184 | 66.001 | 1.00 | 47.25 | E | C |
| ATOM | 8688 | OE1 | GLU | E | 536 | 4.674 | 33.218 | 66.574 | 1.00 | 48.61 | E | O |
| ATOM | 8689 | OE2 | GLU | E | 536 | 5.620 | 31.223 | 66.601 | 1.00 | 48.88 | E | O |
| ATOM | 8690 | C | GLU | E | 536 | 6.048 | 33.395 | 61.558 | 1.00 | 35.11 | E | C |
| ATOM | 8691 | O | GLU | E | 536 | 4.979 | 34.000 | 61.575 | 1.00 | 35.25 | E | O |
| ATOM | 8692 | N | LYS | E | 537 | 7.134 | 33.849 | 60.939 | 1.00 | 33.98 | E | N |
| ATOM | 8693 | CA | LYS | E | 537 | 7.140 | 35.114 | 60.212 | 1.00 | 33.63 | E | C |
| ATOM | 8694 | CB | LYS | E | 537 | 8.505 | 35.356 | 59.567 | 1.00 | 35.25 | E | C |
| ATOM | 8695 | CG | LYS | E | 537 | 9.418 | 36.267 | 60.357 | 1.00 | 41.14 | E | C |
| ATOM | 8696 | CD | LYS | E | 537 | 9.009 | 37.728 | 60.222 | 1.00 | 46.45 | E | C |
| ATOM | 8697 | CE | LYS | E | 537 | 9.958 | 38.635 | 61.005 | 1.00 | 50.63 | E | C |
| ATOM | 8698 | NZ | LYS | E | 537 | 9.293 | 39.875 | 61.517 | 1.00 | 54.78 | E | N |
| ATOM | 8699 | C | LYS | E | 537 | 6.078 | 35.121 | 59.121 | 1.00 | 32.07 | E | C |
| ATOM | 8700 | O | LYS | E | 537 | 5.842 | 34.107 | 58.463 | 1.00 | 32.31 | E | O |
| ATOM | 8701 | N | ASN | E | 538 | 5.436 | 36.267 | 58.936 | 1.00 | 29.10 | E | N |
| ATOM | 8702 | CA | ASN | E | 538 | 4.418 | 36.407 | 57.904 | 1.00 | 26.54 | E | C |
| ATOM | 8703 | CB | ASN | E | 538 | 3.485 | 37.575 | 58.244 | 1.00 | 26.37 | E | C |
| ATOM | 8704 | CG | ASN | E | 538 | 2.149 | 37.491 | 57.529 | 1.00 | 25.89 | E | C |
| ATOM | 8705 | OD1 | ASN | E | 538 | 1.637 | 36.399 | 57.268 | 1.00 | 24.37 | E | O |
| ATOM | 8706 | ND2 | ASN | E | 538 | 1.572 | 38.651 | 57.213 | 1.00 | 24.35 | E | N |
| ATOM | 8707 | C | ASN | E | 538 | 5.154 | 36.706 | 56.607 | 1.00 | 24.18 | E | C |
| ATOM | 8708 | O | ASN | E | 538 | 6.078 | 37.516 | 56.588 | 1.00 | 22.70 | E | O |
| ATOM | 8709 | N | PRO | E | 539 | 4.784 | 36.030 | 55.512 | 1.00 | 24.01 | E | N |
| ATOM | 8710 | CD | PRO | E | 539 | 3.770 | 34.974 | 55.369 | 1.00 | 23.39 | E | C |
| ATOM | 8711 | CA | PRO | E | 539 | 5.473 | 36.310 | 54.243 | 1.00 | 24.74 | E | C |
| ATOM | 8712 | CB | PRO | E | 539 | 4.848 | 35.312 | 53.260 | 1.00 | 22.70 | E | C |
| ATOM | 8713 | CG | PRO | E | 539 | 4.213 | 34.258 | 54.121 | 1.00 | 23.11 | E | C |
| ATOM | 8714 | C | PRO | E | 539 | 5.236 | 37.770 | 53.819 | 1.00 | 24.26 | E | C |
| ATOM | 8715 | O | PRO | E | 539 | 4.285 | 38.405 | 54.282 | 1.00 | 25.76 | E | O |
| ATOM | 8716 | N | SER | E | 540 | 6.098 | 38.297 | 52.951 | 1.00 | 23.60 | E | N |
| ATOM | 8717 | CA | SER | E | 540 | 5.975 | 39.674 | 52.474 | 1.00 | 21.59 | E | C |
| ATOM | 8718 | CB | SER | E | 540 | 7.240 | 40.082 | 51.714 | 1.00 | 21.20 | E | C |
| ATOM | 8719 | OG | SER | E | 540 | 7.301 | 39.470 | 50.440 | 1.00 | 20.84 | E | O |
| ATOM | 8720 | C | SER | E | 540 | 4.749 | 39.878 | 51.580 | 1.00 | 21.76 | E | C |
| ATOM | 8721 | O | SER | E | 540 | 4.130 | 38.916 | 51.125 | 1.00 | 22.12 | E | O |
| ATOM | 8722 | N | TYR | E | 541 | 4.402 | 41.141 | 51.346 | 1.00 | 21.19 | E | N |
| ATOM | 8723 | CA | TYR | E | 541 | 3.261 | 41.503 | 50.513 | 1.00 | 19.74 | E | C |
| ATOM | 8724 | CB | TYR | E | 541 | 3.194 | 43.031 | 50.373 | 1.00 | 17.86 | E | C |
| ATOM | 8725 | CG | TYR | E | 541 | 2.044 | 43.555 | 49.536 | 1.00 | 19.04 | E | C |
| ATOM | 8726 | CD1 | TYR | E | 541 | 2.137 | 43.615 | 48.144 | 1.00 | 17.80 | E | C |
| ATOM | 8727 | CE1 | TYR | E | 541 | 1.085 | 44.110 | 47.375 | 1.00 | 17.37 | E | C |
| ATOM | 8728 | CD2 | TYR | E | 541 | 0.866 | 44.003 | 50.136 | 1.00 | 17.37 | E | C |
| ATOM | 8729 | CE2 | TYR | E | 541 | −0.190 | 44.500 | 49.374 | 1.00 | 17.14 | E | C |
| ATOM | 8730 | CZ | TYR | E | 541 | −0.074 | 44.551 | 47.993 | 1.00 | 17.61 | E | C |
| ATOM | 8731 | OH | TYR | E | 541 | −1.113 | 45.044 | 47.235 | 1.00 | 15.05 | E | O |
| ATOM | 8732 | C | TYR | E | 541 | 3.375 | 40.853 | 49.132 | 1.00 | 21.16 | E | C |
| ATOM | 8733 | O | TYR | E | 541 | 2.410 | 40.281 | 48.620 | 1.00 | 23.11 | E | O |
| ATOM | 8734 | N | THR | E | 542 | 4.561 | 40.937 | 48.538 | 1.00 | 20.03 | E | N |
| ATOM | 8735 | CA | THR | E | 542 | 4.800 | 40.374 | 47.214 | 1.00 | 20.77 | E | C |
| ATOM | 8736 | CB | THR | E | 542 | 6.183 | 40.812 | 46.694 | 1.00 | 19.88 | E | C |
| ATOM | 8737 | OG1 | THR | E | 542 | 6.214 | 42.241 | 46.623 | 1.00 | 17.36 | E | O |
| ATOM | 8738 | CG2 | THR | E | 542 | 6.457 | 40.230 | 45.312 | 1.00 | 18.95 | E | C |
| ATOM | 8739 | C | THR | E | 542 | 4.673 | 38.850 | 47.192 | 1.00 | 21.64 | E | C |
| ATOM | 8740 | O | THR | E | 542 | 4.181 | 38.276 | 46.220 | 1.00 | 22.63 | E | O |
| ATOM | 8741 | N | TYR | E | 543 | 5.108 | 38.200 | 48.267 | 1.00 | 21.81 | E | N |
| ATOM | 8742 | CA | TYR | E | 543 | 5.010 | 36.745 | 48.385 | 1.00 | 20.44 | E | C |
| ATOM | 8743 | CB | TYR | E | 543 | 5.608 | 36.302 | 49.722 | 1.00 | 21.23 | E | C |
| ATOM | 8744 | CG | TYR | E | 543 | 5.812 | 34.811 | 49.873 | 1.00 | 19.66 | E | C |
| ATOM | 8745 | CD1 | TYR | E | 543 | 4.752 | 33.970 | 50.213 | 1.00 | 19.68 | E | C |
| ATOM | 8746 | CE1 | TYR | E | 543 | 4.941 | 32.601 | 50.385 | 1.00 | 18.66 | E | C |
| ATOM | 8747 | CD2 | TYR | E | 543 | 7.069 | 34.247 | 49.707 | 1.00 | 20.55 | E | C |
| ATOM | 8748 | CE2 | TYR | E | 543 | 7.274 | 32.879 | 49.876 | 1.00 | 21.56 | E | C |
| ATOM | 8749 | CZ | TYR | E | 543 | 6.205 | 32.063 | 50.215 | 1.00 | 20.69 | E | C |
| ATOM | 8750 | OH | TYR | E | 543 | 6.411 | 30.712 | 50.381 | 1.00 | 20.17 | E | O |
| ATOM | 8751 | C | TYR | E | 543 | 3.524 | 36.367 | 48.323 | 1.00 | 21.29 | E | C |
| ATOM | 8752 | O | TYR | E | 543 | 3.109 | 35.487 | 47.559 | 1.00 | 20.91 | E | O |
| ATOM | 8753 | N | TYR | E | 544 | 2.725 | 37.046 | 49.136 | 1.00 | 20.60 | E | N |
| ATOM | 8754 | CA | TYR | E | 544 | 1.292 | 36.807 | 49.166 | 1.00 | 21.00 | E | C |
| ATOM | 8755 | CB | TYR | E | 544 | 0.619 | 37.763 | 50.164 | 1.00 | 21.23 | E | C |
| ATOM | 8756 | CG | TYR | E | 544 | 0.439 | 37.225 | 51.570 | 1.00 | 22.43 | E | C |
| ATOM | 8757 | CD1 | TYR | E | 544 | 1.418 | 37.425 | 52.550 | 1.00 | 22.63 | E | C |
| ATOM | 8758 | CE1 | TYR | E | 544 | 1.230 | 36.972 | 53.860 | 1.00 | 20.96 | E | C |
| ATOM | 8759 | CD2 | TYR | E | 544 | −0.730 | 36.555 | 51.936 | 1.00 | 21.56 | E | C |
| ATOM | 8760 | CE2 | TYR | E | 544 | −0.923 | 36.101 | 53.241 | 1.00 | 20.96 | E | C |
| ATOM | 8761 | CZ | TYR | E | 544 | 0.056 | 36.314 | 54.195 | 1.00 | 21.15 | E | C |
| ATOM | 8762 | OH | TYR | E | 544 | −0.156 | 35.887 | 55.486 | 1.00 | 19.78 | E | O |
| ATOM | 8763 | C | TYR | E | 544 | 0.722 | 37.060 | 47.759 | 1.00 | 22.15 | E | C |
| ATOM | 8764 | O | TYR | E | 544 | −0.003 | 36.227 | 47.209 | 1.00 | 21.51 | E | O |
| ATOM | 8765 | N | ALA | E | 545 | 1.063 | 38.216 | 47.187 | 1.00 | 22.78 | E | N |
| ATOM | 8766 | CA | ALA | E | 545 | 0.584 | 38.615 | 45.864 | 1.00 | 22.05 | E | C |
| ATOM | 8767 | CB | ALA | E | 545 | 1.176 | 39.970 | 45.489 | 1.00 | 21.66 | E | C |
| ATOM | 8768 | C | ALA | E | 545 | 0.888 | 37.595 | 44.769 | 1.00 | 22.55 | E | C |
| ATOM | 8769 | O | ALA | E | 545 | 0.002 | 37.220 | 43.999 | 1.00 | 21.78 | E | O |
| ATOM | 8770 | N | TYR | E | 546 | 2.134 | 37.138 | 44.697 | 1.00 | 22.45 | E | N |
| ATOM | 8771 | CA | TYR | E | 546 | 2.499 | 36.177 | 43.667 | 1.00 | 22.33 | E | C |
| ATOM | 8772 | CB | TYR | E | 546 | 3.977 | 35.789 | 43.780 | 1.00 | 23.92 | E | C |
| ATOM | 8773 | CG | TYR | E | 546 | 4.354 | 34.691 | 42.810 | 1.00 | 27.09 | E | C |
| ATOM | 8774 | CD1 | TYR | E | 546 | 4.649 | 34.982 | 41.476 | 1.00 | 27.49 | E | C |
| ATOM | 8775 | CE1 | TYR | E | 546 | 4.897 | 33.969 | 40.557 | 1.00 | 26.65 | E | C |
| ATOM | 8776 | CD2 | TYR | E | 546 | 4.327 | 33.352 | 43.200 | 1.00 | 27.33 | E | C |
| ATOM | 8777 | CE2 | TYR | E | 546 | 4.572 | 32.334 | 42.290 | 1.00 | 27.27 | E | C |
| ATOM | 8778 | CZ | TYR | E | 546 | 4.851 | 32.650 | 40.970 | 1.00 | 28.60 | E | C |
| ATOM | 8779 | OH | TYR | E | 546 | 5.054 | 31.639 | 40.059 | 1.00 | 31.36 | E | O |
| ATOM | 8780 | C | TYR | E | 546 | 1.653 | 34.910 | 43.708 | 1.00 | 21.82 | E | C |
| ATOM | 8781 | O | TYR | E | 546 | 1.094 | 34.485 | 42.695 | 1.00 | 22.35 | E | O |
| ATOM | 8782 | N | TYR | E | 547 | 1.554 | 34.309 | 44.888 | 1.00 | 21.55 | E | N |
| ATOM | 8783 | CA | TYR | E | 547 | 0.808 | 33.070 | 45.036 | 1.00 | 20.44 | E | C |
| ATOM | 8784 | CB | TYR | E | 547 | 1.177 | 32.408 | 46.368 | 1.00 | 19.22 | E | C |
| ATOM | 8785 | CG | TYR | E | 547 | 2.547 | 31.762 | 46.285 | 1.00 | 17.90 | E | C |
| ATOM | 8786 | CD1 | TYR | E | 547 | 2.737 | 30.603 | 45.537 | 1.00 | 16.80 | E | C |
| ATOM | 8787 | CE1 | TYR | E | 547 | 4.002 | 30.053 | 45.368 | 1.00 | 15.57 | E | C |
| ATOM | 8788 | CD2 | TYR | E | 547 | 3.670 | 32.356 | 46.873 | 1.00 | 18.80 | E | C |
| ATOM | 8789 | CE2 | TYR | E | 547 | 4.946 | 31.808 | 46.707 | 1.00 | 14.81 | E | C |
| ATOM | 8790 | CZ | TYR | E | 547 | 5.098 | 30.655 | 45.949 | 1.00 | 16.72 | E | C |
| ATOM | 8791 | OH | TYR | E | 547 | 6.345 | 30.092 | 45.760 | 1.00 | 20.10 | E | O |
| ATOM | 8792 | C | TYR | E | 547 | −0.693 | 33.204 | 44.862 | 1.00 | 20.45 | E | C |
| ATOM | 8793 | O | TYR | E | 547 | −1.379 | 32.235 | 44.522 | 1.00 | 20.33 | E | O |
| ATOM | 8794 | N | MET | E | 548 | −1.211 | 34.404 | 45.075 | 1.00 | 19.93 | E | N |
| ATOM | 8795 | CA | MET | E | 548 | −2.631 | 34.622 | 44.878 | 1.00 | 20.76 | E | C |
| ATOM | 8796 | CB | MET | E | 548 | −3.082 | 35.880 | 45.618 | 1.00 | 22.57 | E | C |
| ATOM | 8797 | CG | MET | E | 548 | −3.547 | 35.594 | 47.034 | 1.00 | 23.97 | E | C |
| ATOM | 8798 | SD | MET | E | 548 | −4.613 | 36.883 | 47.651 | 1.00 | 30.26 | E | S |
| ATOM | 8799 | CE | MET | E | 548 | −6.223 | 36.329 | 47.075 | 1.00 | 26.34 | E | C |
| ATOM | 8800 | C | MET | E | 548 | −2.833 | 34.773 | 43.371 | 1.00 | 21.41 | E | C |
| ATOM | 8801 | O | MET | E | 548 | −3.825 | 34.300 | 42.809 | 1.00 | 20.98 | E | O |
| ATOM | 8802 | N | TYR | E | 549 | −1.871 | 35.417 | 42.717 | 1.00 | 19.91 | E | N |
| ATOM | 8803 | CA | TYR | E | 549 | −1.940 | 35.616 | 41.275 | 1.00 | 21.20 | E | C |
| ATOM | 8804 | CB | TYR | E | 549 | −0.812 | 36.551 | 40.811 | 1.00 | 20.30 | E | C |
| ATOM | 8805 | CG | TYR | E | 549 | −0.609 | 36.571 | 39.312 | 1.00 | 20.89 | E | C |
| ATOM | 8806 | CD1 | TYR | E | 549 | −1.431 | 37.340 | 38.489 | 1.00 | 20.00 | E | C |
| ATOM | 8807 | CE1 | TYR | E | 549 | −1.274 | 37.336 | 37.104 | 1.00 | 21.86 | E | C |
| ATOM | 8808 | CD2 | TYR | E | 549 | 0.389 | 35.794 | 38.710 | 1.00 | 21.71 | E | C |
| ATOM | 8809 | CE2 | TYR | E | 549 | 0.557 | 35.781 | 37.323 | 1.00 | 21.59 | E | C |
| ATOM | 8810 | CZ | TYR | E | 549 | −0.282 | 36.555 | 36.530 | 1.00 | 22.02 | E | C |
| ATOM | 8811 | OH | TYR | E | 549 | −0.146 | 36.546 | 35.166 | 1.00 | 22.47 | E | O |
| ATOM | 8812 | C | TYR | E | 549 | −1.816 | 34.267 | 40.565 | 1.00 | 21.08 | E | C |
| ATOM | 8813 | O | TYR | E | 549 | −2.598 | 33.942 | 39.673 | 1.00 | 20.45 | E | O |
| ATOM | 8814 | N | ALA | E | 550 | −0.827 | 33.486 | 40.986 | 1.00 | 21.80 | E | N |
| ATOM | 8815 | CA | ALA | E | 550 | −0.555 | 32.179 | 40.407 | 1.00 | 21.69 | E | C |
| ATOM | 8816 | CB | ALA | E | 550 | 0.646 | 31.549 | 41.111 | 1.00 | 20.29 | E | C |
| ATOM | 8817 | C | ALA | E | 550 | −1.749 | 31.225 | 40.445 | 1.00 | 22.55 | E | C |
| ATOM | 8818 | O | ALA | E | 550 | −2.059 | 30.570 | 39.446 | 1.00 | 22.31 | E | O |
| ATOM | 8819 | N | ASN | E | 551 | −2.416 | 31.139 | 41.593 | 1.00 | 22.14 | E | N |
| ATOM | 8820 | CA | ASN | E | 551 | −3.566 | 30.251 | 41.731 | 1.00 | 21.45 | E | C |
| ATOM | 8821 | CB | ASN | E | 551 | −3.899 | 30.050 | 43.213 | 1.00 | 22.40 | E | C |
| ATOM | 8822 | CG | ASN | E | 551 | −3.009 | 29.018 | 43.872 | 1.00 | 22.18 | E | C |
| ATOM | 8823 | OD1 | ASN | E | 551 | −2.026 | 29.357 | 44.538 | 1.00 | 22.20 | E | O |
| ATOM | 8824 | ND2 | ASN | E | 551 | −3.343 | 27.748 | 43.685 | 1.00 | 20.83 | E | N |
| ATOM | 8825 | C | ASN | E | 551 | −4.801 | 30.769 | 40.988 | 1.00 | 22.39 | E | C |
| ATOM | 8826 | O | ASN | E | 551 | −5.586 | 29.986 | 40.456 | 1.00 | 23.70 | E | O |
| ATOM | 8827 | N | ILE | E | 552 | −4.982 | 32.085 | 40.955 | 1.00 | 21.10 | E | N |
| ATOM | 8828 | CA | ILE | E | 552 | −6.125 | 32.666 | 40.263 | 1.00 | 19.74 | E | C |
| ATOM | 8829 | CB | ILE | E | 552 | −6.271 | 34.181 | 40.606 | 1.00 | 18.28 | E | C |
| ATOM | 8830 | CG2 | ILE | E | 552 | −7.219 | 34.873 | 39.619 | 1.00 | 14.26 | E | C |
| ATOM | 8831 | CG1 | ILE | E | 552 | −6.812 | 34.324 | 42.040 | 1.00 | 17.30 | E | C |
| ATOM | 8832 | CD1 | ILE | E | 552 | −6.762 | 35.733 | 42.591 | 1.00 | 13.79 | E | C |
| ATOM | 8833 | C | ILE | E | 552 | −5.964 | 32.471 | 38.750 | 1.00 | 19.28 | E | C |
| ATOM | 8834 | O | ILE | E | 552 | −6.932 | 32.229 | 38.034 | 1.00 | 18.63 | E | O |
| ATOM | 8835 | N | MET | E | 553 | −4.729 | 32.557 | 38.275 | 1.00 | 21.95 | E | N |
| ATOM | 8836 | CA | MET | E | 553 | −4.447 | 32.380 | 36.855 | 1.00 | 24.60 | E | C |
| ATOM | 8837 | CB | MET | E | 553 | −2.971 | 32.646 | 36.581 | 1.00 | 25.43 | E | C |
| ATOM | 8838 | CG | MET | E | 553 | −2.525 | 32.238 | 35.206 | 1.00 | 26.65 | E | C |
| ATOM | 8839 | SD | MET | E | 553 | −0.749 | 32.258 | 35.098 | 1.00 | 32.92 | E | S |
| ATOM | 8840 | CE | MET | E | 553 | −0.464 | 30.632 | 34.450 | 1.00 | 33.59 | E | C |
| ATOM | 8841 | C | MET | E | 553 | −4.812 | 30.970 | 36.396 | 1.00 | 24.47 | E | C |
| ATOM | 8842 | O | MET | E | 553 | −5.534 | 30.790 | 35.411 | 1.00 | 24.40 | E | O |
| ATOM | 8843 | N | VAL | E | 554 | −4.312 | 29.971 | 37.117 | 1.00 | 23.39 | E | N |
| ATOM | 8844 | CA | VAL | E | 554 | −4.598 | 28.579 | 36.785 | 1.00 | 22.29 | E | C |
| ATOM | 8845 | CB | VAL | E | 554 | −3.817 | 27.603 | 37.711 | 1.00 | 21.96 | E | C |
| ATOM | 8846 | CG1 | VAL | E | 554 | −4.166 | 26.160 | 37.368 | 1.00 | 21.60 | E | C |
| ATOM | 8847 | CG2 | VAL | E | 554 | −2.317 | 27.824 | 37.560 | 1.00 | 19.24 | E | C |
| ATOM | 8848 | C | VAL | E | 554 | −6.097 | 28.316 | 36.919 | 1.00 | 21.39 | E | C |
| ATOM | 8849 | O | VAL | E | 554 | −6.691 | 27.643 | 36.086 | 1.00 | 23.26 | E | O |
| ATOM | 8850 | N | LEU | E | 555 | −6.709 | 28.864 | 37.963 | 1.00 | 20.92 | E | N |
| ATOM | 8851 | CA | LEU | E | 555 | −8.138 | 28.686 | 38.195 | 1.00 | 19.57 | E | C |
| ATOM | 8852 | CB | LEU | E | 555 | −8.539 | 29.337 | 39.523 | 1.00 | 18.07 | E | C |
| ATOM | 8853 | CG | LEU | E | 555 | −10.026 | 29.347 | 39.905 | 1.00 | 17.51 | E | C |
| ATOM | 8854 | CD1 | LEU | E | 555 | −10.553 | 27.927 | 40.055 | 1.00 | 16.65 | E | C |
| ATOM | 8855 | CD2 | LEU | E | 555 | −10.196 | 30.104 | 41.203 | 1.00 | 16.19 | E | C |
| ATOM | 8856 | C | LEU | E | 555 | −8.959 | 29.290 | 37.066 | 1.00 | 19.00 | E | C |
| ATOM | 8857 | O | LEU | E | 555 | −9.979 | 28.730 | 36.660 | 1.00 | 18.26 | E | O |
| ATOM | 8858 | N | ASN | E | 556 | −8.512 | 30.440 | 36.568 | 1.00 | 19.50 | E | N |
| ATOM | 8859 | CA | ASN | E | 556 | −9.206 | 31.135 | 35.494 | 1.00 | 19.35 | E | C |
| ATOM | 8860 | CB | ASN | E | 556 | −8.627 | 32.544 | 35.326 | 1.00 | 18.03 | E | C |
| ATOM | 8861 | CG | ASN | E | 556 | −9.203 | 33.539 | 36.325 | 1.00 | 17.93 | E | C |
| ATOM | 8862 | OD1 | ASN | E | 556 | −10.233 | 33.285 | 36.953 | 1.00 | 18.98 | E | O |
| ATOM | 8863 | ND2 | ASN | E | 556 | −8.540 | 34.678 | 36.474 | 1.00 | 16.14 | E | N |
| ATOM | 8864 | C | ASN | E | 556 | −9.112 | 30.357 | 34.181 | 1.00 | 20.71 | E | C |
| ATOM | 8865 | O | ASN | E | 556 | −10.063 | 30.338 | 33.399 | 1.00 | 19.30 | E | O |
| ATOM | 8866 | N | SER | E | 557 | −7.968 | 29.715 | 33.947 | 1.00 | 22.89 | E | N |
| ATOM | 8867 | CA | SER | E | 557 | −7.763 | 28.922 | 32.736 | 1.00 | 23.52 | E | C |
| ATOM | 8868 | CB | SER | E | 557 | −6.343 | 28.367 | 32.682 | 1.00 | 22.89 | E | C |
| ATOM | 8869 | OG | SER | E | 557 | −5.407 | 29.405 | 32.480 | 1.00 | 31.20 | E | O |
| ATOM | 8870 | C | SER | E | 557 | −8.738 | 27.760 | 32.756 | 1.00 | 24.98 | E | C |
| ATOM | 8871 | O | SER | E | 557 | −9.415 | 27.478 | 31.766 | 1.00 | 24.59 | E | O |
| ATOM | 8872 | N | LEU | E | 558 | −8.805 | 27.088 | 33.902 | 1.00 | 26.29 | E | N |
| ATOM | 8873 | CA | LEU | E | 558 | −9.694 | 25.949 | 34.071 | 1.00 | 25.84 | E | C |
| ATOM | 8874 | CB | LEU | E | 558 | −9.494 | 25.335 | 35.461 | 1.00 | 26.44 | E | C |
| ATOM | 8875 | CG | LEU | E | 558 | −10.438 | 24.197 | 35.854 | 1.00 | 26.73 | E | C |
| ATOM | 8876 | CD1 | LEU | E | 558 | −10.367 | 23.093 | 34.813 | 1.00 | 26.19 | E | C |
| ATOM | 8877 | CD2 | LEU | E | 558 | −10.053 | 23.663 | 37.216 | 1.00 | 26.14 | E | C |
| ATOM | 8878 | C | LEU | E | 558 | −11.160 | 26.330 | 33.874 | 1.00 | 25.16 | E | C |
| ATOM | 8879 | O | LEU | E | 558 | −11.876 | 25.677 | 33.124 | 1.00 | 25.22 | E | O |
| ATOM | 8880 | N | ARG | E | 559 | −11.601 | 27.394 | 34.537 | 1.00 | 25.62 | E | N |
| ATOM | 8881 | CA | ARG | E | 559 | −12.989 | 27.828 | 34.432 | 1.00 | 25.44 | E | C |
| ATOM | 8882 | CB | ARG | E | 559 | −13.294 | 28.875 | 35.510 | 1.00 | 24.19 | E | C |
| ATOM | 8883 | CG | ARG | E | 559 | −13.688 | 28.263 | 36.854 | 1.00 | 21.81 | E | C |
| ATOM | 8884 | CD | ARG | E | 559 | −13.903 | 29.324 | 37.914 | 1.00 | 19.01 | E | C |
| ATOM | 8885 | NE | ARG | E | 559 | −15.303 | 29.717 | 38.038 | 1.00 | 15.21 | E | N |
| ATOM | 8886 | CZ | ARG | E | 559 | −16.227 | 29.001 | 38.668 | 1.00 | 15.32 | E | C |
| ATOM | 8887 | NH1 | ARG | E | 559 | −15.898 | 27.848 | 39.233 | 1.00 | 14.07 | E | N |
| ATOM | 8888 | NH2 | ARG | E | 559 | −17.476 | 29.441 | 38.747 | 1.00 | 11.97 | E | N |
| ATOM | 8889 | C | ARG | E | 559 | −13.351 | 28.376 | 33.056 | 1.00 | 26.51 | E | C |
| ATOM | 8890 | O | ARG | E | 559 | −14.497 | 28.253 | 32.613 | 1.00 | 25.82 | E | O |
| ATOM | 8891 | N | LYS | E | 560 | −12.380 | 28.988 | 32.385 | 1.00 | 28.73 | E | N |
| ATOM | 8892 | CA | LYS | E | 560 | −12.619 | 29.541 | 31.056 | 1.00 | 29.88 | E | C |
| ATOM | 8893 | CB | LYS | E | 560 | −11.359 | 30.242 | 30.534 | 1.00 | 30.16 | E | C |
| ATOM | 8894 | CG | LYS | E | 560 | −11.448 | 30.708 | 29.085 | 1.00 | 32.64 | E | C |
| ATOM | 8895 | CD | LYS | E | 560 | −12.199 | 32.032 | 28.959 | 1.00 | 35.72 | E | C |
| ATOM | 8896 | CE | LYS | E | 560 | −12.119 | 32.598 | 27.537 | 1.00 | 37.31 | E | C |
| ATOM | 8897 | NZ | LYS | E | 560 | −12.145 | 34.101 | 27.495 | 1.00 | 36.81 | E | N |
| ATOM | 8898 | C | LYS | E | 560 | −12.992 | 28.380 | 30.139 | 1.00 | 30.13 | E | C |
| ATOM | 8899 | O | LYS | E | 560 | −14.009 | 28.416 | 29.446 | 1.00 | 28.89 | E | O |
| ATOM | 8900 | N | GLU | E | 561 | −12.168 | 27.340 | 30.164 | 1.00 | 30.93 | E | N |
| ATOM | 8901 | CA | GLU | E | 561 | −12.396 | 26.164 | 29.344 | 1.00 | 32.85 | E | C |
| ATOM | 8902 | CB | GLU | E | 561 | −11.251 | 25.170 | 29.531 | 1.00 | 37.10 | E | C |
| ATOM | 8903 | CG | GLU | E | 561 | −10.176 | 25.274 | 28.460 | 1.00 | 44.26 | E | C |
| ATOM | 8904 | CD | GLU | E | 561 | −9.108 | 24.208 | 28.605 | 1.00 | 48.73 | E | C |
| ATOM | 8905 | OE1 | GLU | E | 561 | −9.458 | 23.054 | 28.948 | 1.00 | 49.39 | E | O |
| ATOM | 8906 | OE2 | GLU | E | 561 | −7.918 | 24.526 | 28.378 | 1.00 | 50.98 | E | O |
| ATOM | 8907 | C | GLU | E | 561 | −13.726 | 25.480 | 29.641 | 1.00 | 32.00 | E | C |
| ATOM | 8908 | O | GLU | E | 561 | −14.351 | 24.927 | 28.739 | 1.00 | 32.57 | E | O |
| ATOM | 8909 | N | ARG | E | 562 | −14.161 | 25.515 | 30.899 | 1.00 | 30.37 | E | N |
| ATOM | 8910 | CA | ARG | E | 562 | −15.428 | 24.887 | 31.281 | 1.00 | 27.49 | E | C |
| ATOM | 8911 | CB | ARG | E | 562 | −15.473 | 24.617 | 32.793 | 1.00 | 27.39 | E | C |
| ATOM | 8912 | CG | ARG | E | 562 | −14.329 | 23.753 | 33.328 | 1.00 | 29.13 | E | C |
| ATOM | 8913 | CD | ARG | E | 562 | −14.848 | 22.627 | 34.207 | 1.00 | 28.96 | E | C |
| ATOM | 8914 | NE | ARG | E | 562 | −15.941 | 21.893 | 33.569 | 1.00 | 29.89 | E | N |
| ATOM | 8915 | CZ | ARG | E | 562 | −16.683 | 20.964 | 34.167 | 1.00 | 31.56 | E | C |
| ATOM | 8916 | NH1 | ARG | E | 562 | −16.461 | 20.633 | 35.434 | 1.00 | 31.76 | E | N |
| ATOM | 8917 | NH2 | ARG | E | 562 | −17.654 | 20.361 | 33.497 | 1.00 | 32.18 | E | N |
| ATOM | 8918 | C | ARG | E | 562 | −16.596 | 25.785 | 30.903 | 1.00 | 25.29 | E | C |
| ATOM | 8919 | O | ARG | E | 562 | −17.754 | 25.385 | 30.986 | 1.00 | 25.13 | E | O |
| ATOM | 8920 | N | GLY | E | 563 | −16.287 | 27.005 | 30.488 | 1.00 | 24.83 | E | N |
| ATOM | 8921 | CA | GLY | E | 563 | −17.333 | 27.939 | 30.123 | 1.00 | 25.01 | E | C |
| ATOM | 8922 | C | GLY | E | 563 | −17.904 | 28.646 | 31.342 | 1.00 | 26.91 | E | C |
| ATOM | 8923 | O | GLY | E | 563 | −19.002 | 29.211 | 31.284 | 1.00 | 26.66 | E | O |
| ATOM | 8924 | N | MET | E | 564 | −17.156 | 28.620 | 32.447 | 1.00 | 27.15 | E | N |
| ATOM | 8925 | CA | MET | E | 564 | −17.582 | 29.254 | 33.692 | 1.00 | 25.76 | E | C |
| ATOM | 8926 | CB | MET | E | 564 | −17.124 | 28.416 | 34.886 | 1.00 | 26.54 | E | C |
| ATOM | 8927 | CG | MET | E | 564 | −17.899 | 27.122 | 35.084 | 1.00 | 25.18 | E | C |
| ATOM | 8928 | SD | MET | E | 564 | −17.006 | 25.922 | 36.106 | 1.00 | 27.22 | E | S |
| ATOM | 8929 | CE | MET | E | 564 | −18.333 | 24.949 | 36.714 | 1.00 | 24.14 | E | C |
| ATOM | 8930 | C | MET | E | 564 | −16.995 | 30.657 | 33.800 | 1.00 | 25.97 | E | C |
| ATOM | 8931 | O | MET | E | 564 | −16.144 | 31.044 | 32.996 | 1.00 | 27.01 | E | O |
| ATOM | 8932 | N | ASN | E | 565 | −17.443 | 31.417 | 34.800 | 1.00 | 25.09 | E | N |
| ATOM | 8933 | CA | ASN | E | 565 | −16.946 | 32.779 | 35.000 | 1.00 | 22.00 | E | C |
| ATOM | 8934 | CB | ASN | E | 565 | −17.888 | 33.566 | 35.925 | 1.00 | 22.26 | E | C |
| ATOM | 8935 | CG | ASN | E | 565 | −18.076 | 32.907 | 37.284 | 1.00 | 21.96 | E | C |
| ATOM | 8936 | OD1 | ASN | E | 565 | −18.507 | 31.758 | 37.380 | 1.00 | 20.77 | E | O |
| ATOM | 8937 | ND2 | ASN | E | 565 | −17.758 | 33.644 | 38.344 | 1.00 | 20.19 | E | N |
| ATOM | 8938 | C | ASN | E | 565 | −15.534 | 32.764 | 35.570 | 1.00 | 20.91 | E | C |
| ATOM | 8939 | O | ASN | E | 565 | −15.109 | 31.772 | 36.167 | 1.00 | 21.39 | E | O |
| ATOM | 8940 | N | THR | E | 566 | −14.797 | 33.852 | 35.364 | 1.00 | 18.84 | E | N |
| ATOM | 8941 | CA | THR | E | 566 | −13.435 | 33.944 | 35.872 | 1.00 | 17.72 | E | C |
| ATOM | 8942 | CB | THR | E | 566 | −12.424 | 34.190 | 34.730 | 1.00 | 18.78 | E | C |
| ATOM | 8943 | OG1 | THR | E | 566 | −12.809 | 35.351 | 33.985 | 1.00 | 19.12 | E | O |
| ATOM | 8944 | CG2 | THR | E | 566 | −12.385 | 32.990 | 33.793 | 1.00 | 18.29 | E | C |
| ATOM | 8945 | C | THR | E | 566 | −13.367 | 35.069 | 36.905 | 1.00 | 16.32 | E | C |
| ATOM | 8946 | O | THR | E | 566 | −14.329 | 35.815 | 37.068 | 1.00 | 16.64 | E | O |
| ATOM | 8947 | N | PHE | E | 567 | −12.240 | 35.192 | 37.602 | 1.00 | 16.20 | E | N |
| ATOM | 8948 | CA | PHE | E | 567 | −12.107 | 36.210 | 38.646 | 1.00 | 15.09 | E | C |
| ATOM | 8949 | CB | PHE | E | 567 | −11.942 | 35.542 | 40.021 | 1.00 | 13.34 | E | C |
| ATOM | 8950 | CG | PHE | E | 567 | −12.868 | 34.382 | 40.251 | 1.00 | 11.80 | E | C |
| ATOM | 8951 | CD1 | PHE | E | 567 | −14.202 | 34.594 | 40.584 | 1.00 | 12.51 | E | C |
| ATOM | 8952 | CD2 | PHE | E | 567 | −12.411 | 33.078 | 40.119 | 1.00 | 11.77 | E | C |
| ATOM | 8953 | CE1 | PHE | E | 567 | −15.073 | 33.516 | 40.782 | 1.00 | 14.10 | E | C |
| ATOM | 8954 | CE2 | PHE | E | 567 | −13.269 | 31.994 | 40.312 | 1.00 | 11.77 | E | C |
| ATOM | 8955 | CZ | PHE | E | 567 | −14.601 | 32.212 | 40.645 | 1.00 | 10.85 | E | C |
| ATOM | 8956 | C | PHE | E | 567 | −10.971 | 37.193 | 38.460 | 1.00 | 15.72 | E | C |
| ATOM | 8957 | O | PHE | E | 567 | −9.937 | 36.877 | 37.875 | 1.00 | 17.90 | E | O |
| ATOM | 8958 | N | LEU | E | 568 | −11.167 | 38.393 | 38.986 | 1.00 | 15.66 | E | N |
| ATOM | 8959 | CA | LEU | E | 568 | −10.155 | 39.430 | 38.903 | 1.00 | 15.31 | E | C |
| ATOM | 8960 | CB | LEU | E | 568 | −10.814 | 40.791 | 38.638 | 1.00 | 12.95 | E | C |
| ATOM | 8961 | CG | LEU | E | 568 | −11.575 | 40.972 | 37.319 | 1.00 | 11.22 | E | C |
| ATOM | 8962 | CD1 | LEU | E | 568 | −12.088 | 42.390 | 37.235 | 1.00 | 8.24 | E | C |
| ATOM | 8963 | CD2 | LEU | E | 568 | −10.659 | 40.674 | 36.137 | 1.00 | 8.66 | E | C |
| ATOM | 8964 | C | LEU | E | 568 | −9.409 | 39.471 | 40.234 | 1.00 | 16.72 | E | C |
| ATOM | 8965 | O | LEU | E | 568 | −9.932 | 39.018 | 41.259 | 1.00 | 16.09 | E | O |
| ATOM | 8966 | N | PHE | E | 569 | −8.183 | 39.989 | 40.207 | 1.00 | 16.56 | E | N |
| ATOM | 8967 | CA | PHE | E | 569 | −7.377 | 40.137 | 41.411 | 1.00 | 15.51 | E | C |
| ATOM | 8968 | CB | PHE | E | 569 | −5.979 | 39.537 | 41.197 | 1.00 | 15.02 | E | C |
| ATOM | 8969 | CG | PHE | E | 569 | −5.072 | 39.629 | 42.403 | 1.00 | 13.65 | E | C |
| ATOM | 8970 | CD1 | PHE | E | 569 | −5.566 | 39.415 | 43.689 | 1.00 | 13.58 | E | C |
| ATOM | 8971 | CD2 | PHE | E | 569 | −3.720 | 39.935 | 42.248 | 1.00 | 13.21 | E | C |
| ATOM | 8972 | CE1 | PHE | E | 569 | −4.718 | 39.508 | 44.808 | 1.00 | 12.82 | E | C |
| ATOM | 8973 | CE2 | PHE | E | 569 | −2.866 | 40.029 | 43.353 | 1.00 | 13.88 | E | C |
| ATOM | 8974 | CZ | PHE | E | 569 | −3.368 | 39.815 | 44.636 | 1.00 | 12.33 | E | C |
| ATOM | 8975 | C | PHE | E | 569 | −7.301 | 41.650 | 41.643 | 1.00 | 16.63 | E | C |
| ATOM | 8976 | O | PHE | E | 569 | −6.696 | 42.371 | 40.849 | 1.00 | 16.42 | E | O |
| ATOM | 8977 | N | ARG | E | 570 | −7.937 | 42.122 | 42.718 | 1.00 | 15.77 | E | N |
| ATOM | 8978 | CA | ARG | E | 570 | −7.975 | 43.547 | 43.056 | 1.00 | 16.08 | E | C |
| ATOM | 8979 | CB | ARG | E | 570 | −9.382 | 44.097 | 42.797 | 1.00 | 14.00 | E | C |
| ATOM | 8980 | CG | ARG | E | 570 | −9.947 | 43.725 | 41.427 | 1.00 | 12.21 | E | C |
| ATOM | 8981 | CD | ARG | E | 570 | −11.462 | 43.889 | 41.355 | 1.00 | 9.63 | E | C |
| ATOM | 8982 | NE | ARG | E | 570 | −11.896 | 45.219 | 41.777 | 1.00 | 11.72 | E | N |
| ATOM | 8983 | CZ | ARG | E | 570 | −13.151 | 45.652 | 41.736 | 1.00 | 9.36 | E | C |
| ATOM | 8984 | NH1 | ARG | E | 570 | −14.113 | 44.863 | 41.287 | 1.00 | 11.07 | E | N |
| ATOM | 8985 | NH2 | ARG | E | 570 | −13.453 | 46.869 | 42.167 | 1.00 | 9.66 | E | N |
| ATOM | 8986 | C | ARG | E | 570 | −7.590 | 43.767 | 44.525 | 1.00 | 16.50 | E | C |
| ATOM | 8987 | O | ARG | E | 570 | −8.449 | 43.971 | 45.381 | 1.00 | 16.41 | E | O |
| ATOM | 8988 | N | PRO | E | 571 | −6.282 | 43.765 | 44.825 | 1.00 | 16.12 | E | N |
| ATOM | 8989 | CD | PRO | E | 571 | −5.167 | 43.610 | 43.871 | 1.00 | 15.76 | E | C |
| ATOM | 8990 | CA | PRO | E | 571 | −5.793 | 43.952 | 46.196 | 1.00 | 15.69 | E | C |
| ATOM | 8991 | CB | PRO | E | 571 | −4.402 | 43.342 | 46.149 | 1.00 | 15.22 | E | C |
| ATOM | 8992 | CG | PRO | E | 571 | −3.932 | 43.691 | 44.759 | 1.00 | 15.57 | E | C |
| ATOM | 8993 | C | PRO | E | 571 | −5.731 | 45.388 | 46.705 | 1.00 | 17.14 | E | C |
| ATOM | 8994 | O | PRO | E | 571 | −5.775 | 46.348 | 45.929 | 1.00 | 16.07 | E | O |
| ATOM | 8995 | N | HIS | E | 572 | −5.635 | 45.519 | 48.026 | 1.00 | 14.30 | E | N |
| ATOM | 8996 | CA | HIS | E | 572 | −5.487 | 46.826 | 48.645 | 1.00 | 13.78 | E | C |
| ATOM | 8997 | CB | HIS | E | 572 | −5.706 | 46.728 | 50.154 | 1.00 | 12.11 | E | C |
| ATOM | 8998 | CG | HIS | E | 572 | −7.128 | 46.921 | 50.576 | 1.00 | 9.60 | E | C |
| ATOM | 8999 | CD2 | HIS | E | 572 | −7.686 | 47.786 | 51.453 | 1.00 | 12.33 | E | C |
| ATOM | 9000 | ND1 | HIS | E | 572 | −8.163 | 46.156 | 50.082 | 1.00 | 8.46 | E | N |
| ATOM | 9001 | CE1 | HIS | E | 572 | −9.299 | 46.546 | 50.637 | 1.00 | 12.12 | E | C |
| ATOM | 9002 | NE2 | HIS | E | 572 | −9.035 | 47.532 | 51.475 | 1.00 | 10.88 | E | N |
| ATOM | 9003 | C | HIS | E | 572 | −4.019 | 47.079 | 48.334 | 1.00 | 13.48 | E | C |
| ATOM | 9004 | O | HIS | E | 572 | −3.190 | 46.179 | 48.514 | 1.00 | 15.30 | E | O |
| ATOM | 9005 | N | CYS | E | 573 | −3.682 | 48.273 | 47.861 | 1.00 | 12.58 | E | N |
| ATOM | 9006 | CA | CYS | E | 573 | −2.294 | 48.534 | 47.507 | 1.00 | 12.98 | E | C |
| ATOM | 9007 | CB | CYS | E | 573 | −2.019 | 47.942 | 46.122 | 1.00 | 12.68 | E | C |
| ATOM | 9008 | SG | CYS | E | 573 | −0.304 | 48.004 | 45.562 | 1.00 | 17.44 | E | S |
| ATOM | 9009 | C | CYS | E | 573 | −1.947 | 50.010 | 47.508 | 1.00 | 12.77 | E | C |
| ATOM | 9010 | O | CYS | E | 573 | −2.716 | 50.837 | 47.016 | 1.00 | 15.28 | E | O |
| ATOM | 9011 | N | GLY | E | 574 | −0.786 | 50.333 | 48.065 | 1.00 | 13.85 | E | N |
| ATOM | 9012 | CA | GLY | E | 574 | −0.335 | 51.713 | 48.104 | 1.00 | 14.28 | E | C |
| ATOM | 9013 | C | GLY | E | 574 | −0.896 | 52.599 | 49.204 | 1.00 | 16.49 | E | C |
| ATOM | 9014 | O | GLY | E | 574 | −0.678 | 53.816 | 49.193 | 1.00 | 15.18 | E | O |
| ATOM | 9015 | N | GLU | E | 575 | −1.631 | 52.017 | 50.148 | 1.00 | 16.95 | E | N |
| ATOM | 9016 | CA | GLU | E | 575 | −2.180 | 52.810 | 51.247 | 1.00 | 17.91 | E | C |
| ATOM | 9017 | CB | GLU | E | 575 | −3.154 | 51.985 | 52.076 | 1.00 | 15.95 | E | C |
| ATOM | 9018 | CG | GLU | E | 575 | −3.946 | 52.802 | 53.064 | 1.00 | 14.25 | E | C |
| ATOM | 9019 | CD | GLU | E | 575 | −4.920 | 51.955 | 53.841 | 1.00 | 15.53 | E | C |
| ATOM | 9020 | OE1 | GLU | E | 575 | −5.945 | 52.494 | 54.309 | 1.00 | 18.92 | E | O |
| ATOM | 9021 | OE2 | GLU | E | 575 | −4.664 | 50.745 | 53.982 | 1.00 | 15.54 | E | O |
| ATOM | 9022 | C | GLU | E | 575 | −1.022 | 53.266 | 52.127 | 1.00 | 18.22 | E | C |
| ATOM | 9023 | O | GLU | E | 575 | −1.060 | 54.344 | 52.714 | 1.00 | 19.36 | E | O |
| ATOM | 9024 | N | VAL | E | 576 | −0.001 | 52.419 | 52.210 | 1.00 | 19.46 | E | N |
| ATOM | 9025 | CA | VAL | E | 576 | 1.211 | 52.693 | 52.981 | 1.00 | 20.31 | E | C |
| ATOM | 9026 | CB | VAL | E | 576 | 0.944 | 52.750 | 54.502 | 1.00 | 21.41 | E | C |
| ATOM | 9027 | CG1 | VAL | E | 576 | 0.668 | 54.191 | 54.928 | 1.00 | 25.47 | E | C |
| ATOM | 9028 | CG2 | VAL | E | 576 | −0.221 | 51.845 | 54.863 | 1.00 | 24.64 | E | C |
| ATOM | 9029 | C | VAL | E | 576 | 2.193 | 51.566 | 52.710 | 1.00 | 19.09 | E | C |
| ATOM | 9030 | O | VAL | E | 576 | 1.916 | 50.678 | 51.911 | 1.00 | 19.28 | E | O |
| ATOM | 9031 | N | GLY | E | 577 | 3.341 | 51.597 | 53.369 | 1.00 | 18.85 | E | N |
| ATOM | 9032 | CA | GLY | E | 577 | 4.314 | 50.545 | 53.154 | 1.00 | 20.14 | E | C |
| ATOM | 9033 | C | GLY | E | 577 | 5.279 | 50.850 | 52.023 | 1.00 | 20.99 | E | C |
| ATOM | 9034 | O | GLY | E | 577 | 5.371 | 51.990 | 51.568 | 1.00 | 20.72 | E | O |
| ATOM | 9035 | N | ALA | E | 578 | 5.989 | 49.822 | 51.569 | 1.00 | 20.96 | E | N |
| ATOM | 9036 | CA | ALA | E | 578 | 6.972 | 49.948 | 50.496 | 1.00 | 22.50 | E | C |
| ATOM | 9037 | CB | ALA | E | 578 | 7.851 | 48.700 | 50.465 | 1.00 | 22.01 | E | C |
| ATOM | 9038 | C | ALA | E | 578 | 6.360 | 50.183 | 49.112 | 1.00 | 22.54 | E | C |
| ATOM | 9039 | O | ALA | E | 578 | 5.242 | 49.758 | 48.830 | 1.00 | 22.67 | E | O |
| ATOM | 9040 | N | LEU | E | 579 | 7.114 | 50.855 | 48.249 | 1.00 | 25.02 | E | N |
| ATOM | 9041 | CA | LEU | E | 579 | 6.667 | 51.148 | 46.890 | 1.00 | 25.37 | E | C |
| ATOM | 9042 | CB | LEU | E | 579 | 7.661 | 52.076 | 46.186 | 1.00 | 24.89 | E | C |
| ATOM | 9043 | CG | LEU | E | 579 | 7.503 | 53.574 | 46.437 | 1.00 | 25.47 | E | C |
| ATOM | 9044 | CD1 | LEU | E | 579 | 8.648 | 54.306 | 45.780 | 1.00 | 25.78 | E | C |
| ATOM | 9045 | CD2 | LEU | E | 579 | 6.172 | 54.059 | 45.893 | 1.00 | 26.70 | E | C |
| ATOM | 9046 | C | LEU | E | 579 | 6.555 | 49.862 | 46.097 | 1.00 | 25.56 | E | C |
| ATOM | 9047 | O | LEU | E | 579 | 5.737 | 49.755 | 45.182 | 1.00 | 27.54 | E | O |
| ATOM | 9048 | N | THR | E | 580 | 7.386 | 48.887 | 46.450 | 1.00 | 24.89 | E | N |
| ATOM | 9049 | CA | THR | E | 580 | 7.385 | 47.608 | 45.763 | 1.00 | 24.35 | E | C |
| ATOM | 9050 | CB | THR | E | 580 | 8.373 | 46.624 | 46.421 | 1.00 | 25.80 | E | C |
| ATOM | 9051 | OG1 | THR | E | 580 | 7.943 | 46.322 | 47.752 | 1.00 | 28.66 | E | O |
| ATOM | 9052 | CG2 | THR | E | 580 | 9.759 | 47.236 | 46.476 | 1.00 | 27.24 | E | C |
| ATOM | 9053 | C | THR | E | 580 | 5.997 | 46.980 | 45.728 | 1.00 | 23.52 | E | C |
| ATOM | 9054 | O | THR | E | 580 | 5.754 | 46.060 | 44.952 | 1.00 | 25.65 | E | O |
| ATOM | 9055 | N | HIS | E | 581 | 5.088 | 47.470 | 46.566 | 1.00 | 21.12 | E | N |
| ATOM | 9056 | CA | HIS | E | 581 | 3.730 | 46.941 | 46.588 | 1.00 | 20.50 | E | C |
| ATOM | 9057 | CB | HIS | E | 581 | 2.945 | 47.469 | 47.796 | 1.00 | 20.43 | E | C |
| ATOM | 9058 | CG | HIS | E | 581 | 3.444 | 46.973 | 49.116 | 1.00 | 20.61 | E | C |
| ATOM | 9059 | CD2 | HIS | E | 581 | 4.527 | 46.229 | 49.441 | 1.00 | 20.44 | E | C |
| ATOM | 9060 | ND1 | HIS | E | 581 | 2.810 | 47.268 | 50.306 | 1.00 | 19.31 | E | N |
| ATOM | 9061 | CE1 | HIS | E | 581 | 3.485 | 46.729 | 51.305 | 1.00 | 17.81 | E | C |
| ATOM | 9062 | NE2 | HIS | E | 581 | 4.531 | 46.094 | 50.808 | 1.00 | 18.05 | E | N |
| ATOM | 9063 | C | HIS | E | 581 | 2.993 | 47.377 | 45.331 | 1.00 | 19.47 | E | C |
| ATOM | 9064 | O | HIS | E | 581 | 2.162 | 46.639 | 44.804 | 1.00 | 18.92 | E | O |
| ATOM | 9065 | N | LEU | E | 582 | 3.287 | 48.589 | 44.867 | 1.00 | 17.88 | E | N |
| ATOM | 9066 | CA | LEU | E | 582 | 2.619 | 49.127 | 43.686 | 1.00 | 19.30 | E | C |
| ATOM | 9067 | CB | LEU | E | 582 | 2.712 | 50.659 | 43.688 | 1.00 | 16.88 | E | C |
| ATOM | 9068 | CG | LEU | E | 582 | 1.785 | 51.307 | 44.728 | 1.00 | 14.96 | E | C |
| ATOM | 9069 | CD1 | LEU | E | 582 | 2.303 | 52.670 | 45.127 | 1.00 | 15.05 | E | C |
| ATOM | 9070 | CD2 | LEU | E | 582 | 0.379 | 51.411 | 44.157 | 1.00 | 13.86 | E | C |
| ATOM | 9071 | C | LEU | E | 582 | 3.210 | 48.535 | 42.416 | 1.00 | 19.85 | E | C |
| ATOM | 9072 | O | LEU | E | 582 | 2.537 | 48.430 | 41.386 | 1.00 | 21.35 | E | O |
| ATOM | 9073 | N | MET | E | 583 | 4.469 | 48.126 | 42.506 | 1.00 | 20.30 | E | N |
| ATOM | 9074 | CA | MET | E | 583 | 5.153 | 47.525 | 41.380 | 1.00 | 19.96 | E | C |
| ATOM | 9075 | CB | MET | E | 583 | 6.650 | 47.493 | 41.664 | 1.00 | 22.44 | E | C |
| ATOM | 9076 | CG | MET | E | 583 | 7.481 | 46.838 | 40.590 | 1.00 | 27.99 | E | C |
| ATOM | 9077 | SD | MET | E | 583 | 8.323 | 45.378 | 41.235 | 1.00 | 37.07 | E | S |
| ATOM | 9078 | CE | MET | E | 583 | 7.092 | 44.147 | 40.947 | 1.00 | 30.70 | E | C |
| ATOM | 9079 | C | MET | E | 583 | 4.604 | 46.111 | 41.171 | 1.00 | 19.52 | E | C |
| ATOM | 9080 | O | MET | E | 583 | 4.383 | 45.678 | 40.039 | 1.00 | 20.02 | E | O |
| ATOM | 9081 | N | THR | E | 584 | 4.363 | 45.402 | 42.270 | 1.00 | 18.30 | E | N |
| ATOM | 9082 | CA | THR | E | 584 | 3.845 | 44.035 | 42.209 | 1.00 | 17.42 | E | C |
| ATOM | 9083 | CB | THR | E | 584 | 3.924 | 43.353 | 43.609 | 1.00 | 16.82 | E | C |
| ATOM | 9084 | OG1 | THR | E | 584 | 5.294 | 43.244 | 44.003 | 1.00 | 14.41 | E | O |
| ATOM | 9085 | CG2 | THR | E | 584 | 3.332 | 41.956 | 43.572 | 1.00 | 17.64 | E | C |
| ATOM | 9086 | C | THR | E | 584 | 2.406 | 44.014 | 41.691 | 1.00 | 17.19 | E | C |
| ATOM | 9087 | O | THR | E | 584 | 1.987 | 43.062 | 41.027 | 1.00 | 17.84 | E | O |
| ATOM | 9088 | N | ALA | E | 585 | 1.651 | 45.062 | 41.997 | 1.00 | 16.38 | E | N |
| ATOM | 9089 | CA | ALA | E | 585 | 0.270 | 45.158 | 41.535 | 1.00 | 16.41 | E | C |
| ATOM | 9090 | CB | ALA | E | 585 | −0.467 | 46.246 | 42.295 | 1.00 | 14.56 | E | C |
| ATOM | 9091 | C | ALA | E | 585 | 0.268 | 45.471 | 40.039 | 1.00 | 16.61 | E | C |
| ATOM | 9092 | O | ALA | E | 585 | −0.644 | 45.074 | 39.314 | 1.00 | 16.40 | E | O |
| ATOM | 9093 | N | PHE | E | 586 | 1.287 | 46.196 | 39.587 | 1.00 | 16.09 | E | N |
| ATOM | 9094 | CA | PHE | E | 586 | 1.407 | 46.535 | 38.177 | 1.00 | 16.98 | E | C |
| ATOM | 9095 | CB | PHE | E | 586 | 2.642 | 47.418 | 37.938 | 1.00 | 16.13 | E | C |
| ATOM | 9096 | CG | PHE | E | 586 | 2.876 | 47.765 | 36.487 | 1.00 | 16.75 | E | C |
| ATOM | 9097 | CD1 | PHE | E | 586 | 2.166 | 48.799 | 35.879 | 1.00 | 15.92 | E | C |
| ATOM | 9098 | CD2 | PHE | E | 586 | 3.792 | 47.045 | 35.725 | 1.00 | 17.03 | E | C |
| ATOM | 9099 | CE1 | PHE | E | 586 | 2.363 | 49.106 | 34.540 | 1.00 | 16.23 | E | C |
| ATOM | 9100 | CE2 | PHE | E | 586 | 3.999 | 47.343 | 34.382 | 1.00 | 16.44 | E | C |
| ATOM | 9101 | CZ | PHE | E | 586 | 3.285 | 48.373 | 33.787 | 1.00 | 17.02 | E | C |
| ATOM | 9102 | C | PHE | E | 586 | 1.533 | 45.236 | 37.377 | 1.00 | 17.63 | E | C |
| ATOM | 9103 | O | PHE | E | 586 | 1.019 | 45.134 | 36.261 | 1.00 | 19.69 | E | O |
| ATOM | 9104 | N | MET | E | 587 | 2.200 | 44.245 | 37.965 | 1.00 | 15.52 | E | N |
| ATOM | 9105 | CA | MET | E | 587 | 2.403 | 42.950 | 37.316 | 1.00 | 16.72 | E | C |
| ATOM | 9106 | CB | MET | E | 587 | 3.655 | 42.254 | 37.862 | 1.00 | 16.50 | E | C |
| ATOM | 9107 | CG | MET | E | 587 | 4.950 | 43.021 | 37.783 | 1.00 | 19.85 | E | C |
| ATOM | 9108 | SD | MET | E | 587 | 6.320 | 42.046 | 38.483 | 1.00 | 23.92 | E | S |
| ATOM | 9109 | CE | MET | E | 587 | 6.303 | 40.565 | 37.443 | 1.00 | 20.26 | E | C |
| ATOM | 9110 | C | MET | E | 587 | 1.263 | 41.945 | 37.478 | 1.00 | 17.30 | E | C |
| ATOM | 9111 | O | MET | E | 587 | 1.051 | 41.102 | 36.606 | 1.00 | 18.02 | E | O |
| ATOM | 9112 | N | THR | E | 588 | 0.523 | 42.039 | 38.581 | 1.00 | 17.13 | E | N |
| ATOM | 9113 | CA | THR | E | 588 | −0.506 | 41.043 | 38.885 | 1.00 | 15.23 | E | C |
| ATOM | 9114 | CB | THR | E | 588 | −0.130 | 40.300 | 40.189 | 1.00 | 15.52 | E | C |
| ATOM | 9115 | OG1 | THR | E | 588 | −0.044 | 41.254 | 41.255 | 1.00 | 15.49 | E | O |
| ATOM | 9116 | CG2 | THR | E | 588 | 1.219 | 39.601 | 40.059 | 1.00 | 14.39 | E | C |
| ATOM | 9117 | C | THR | E | 588 | −1.972 | 41.415 | 39.042 | 1.00 | 14.54 | E | C |
| ATOM | 9118 | O | THR | E | 588 | −2.827 | 40.523 | 39.023 | 1.00 | 14.54 | E | O |
| ATOM | 9119 | N | ALA | E | 589 | −2.287 | 42.695 | 39.198 | 1.00 | 13.46 | E | N |
| ATOM | 9120 | CA | ALA | E | 589 | −3.679 | 43.061 | 39.432 | 1.00 | 13.81 | E | C |
| ATOM | 9121 | CB | ALA | E | 589 | −3.778 | 43.833 | 40.753 | 1.00 | 14.27 | E | C |
| ATOM | 9122 | C | ALA | E | 589 | −4.431 | 43.824 | 38.347 | 1.00 | 14.67 | E | C |
| ATOM | 9123 | O | ALA | E | 589 | −3.875 | 44.690 | 37.680 | 1.00 | 15.18 | E | O |
| ATOM | 9124 | N | ASP | E | 590 | −5.713 | 43.496 | 38.199 | 1.00 | 14.67 | E | N |
| ATOM | 9125 | CA | ASP | E | 590 | −6.579 | 44.159 | 37.239 | 1.00 | 16.97 | E | C |
| ATOM | 9126 | CB | ASP | E | 590 | −7.957 | 43.503 | 37.242 | 1.00 | 16.18 | E | C |
| ATOM | 9127 | CG | ASP | E | 590 | −8.868 | 44.054 | 36.158 | 1.00 | 19.00 | E | C |
| ATOM | 9128 | OD1 | ASP | E | 590 | −9.622 | 45.010 | 36.442 | 1.00 | 17.69 | E | O |
| ATOM | 9129 | OD2 | ASP | E | 590 | −8.835 | 43.530 | 35.022 | 1.00 | 17.28 | E | O |
| ATOM | 9130 | C | ASP | E | 590 | −6.691 | 45.629 | 37.659 | 1.00 | 18.55 | E | C |
| ATOM | 9131 | O | ASP | E | 590 | −6.503 | 46.536 | 36.852 | 1.00 | 19.44 | E | O |
| ATOM | 9132 | N | ASN | E | 591 | −7.008 | 45.854 | 38.931 | 1.00 | 18.36 | E | N |
| ATOM | 9133 | CA | ASN | E | 591 | −7.111 | 47.205 | 39.479 | 1.00 | 16.70 | E | C |
| ATOM | 9134 | CB | ASN | E | 591 | −8.491 | 47.822 | 39.185 | 1.00 | 14.79 | E | C |
| ATOM | 9135 | CG | ASN | E | 591 | −9.627 | 47.071 | 39.836 | 1.00 | 15.45 | E | C |
| ATOM | 9136 | OD1 | ASN | E | 591 | −10.327 | 46.285 | 39.190 | 1.00 | 15.13 | E | O |
| ATOM | 9137 | ND2 | ASN | E | 591 | −9.826 | 47.312 | 41.121 | 1.00 | 13.54 | E | N |
| ATOM | 9138 | C | ASN | E | 591 | −6.826 | 47.147 | 40.986 | 1.00 | 16.89 | E | C |
| ATOM | 9139 | O | ASN | E | 591 | −6.708 | 46.060 | 41.550 | 1.00 | 14.40 | E | O |
| ATOM | 9140 | N | ILE | E | 592 | −6.699 | 48.307 | 41.630 | 1.00 | 17.81 | E | N |
| ATOM | 9141 | CA | ILE | E | 592 | −6.392 | 48.345 | 43.062 | 1.00 | 16.02 | E | C |
| ATOM | 9142 | CB | ILE | E | 592 | −4.910 | 48.738 | 43.312 | 1.00 | 15.34 | E | C |
| ATOM | 9143 | CG2 | ILE | E | 592 | −3.971 | 47.756 | 42.633 | 1.00 | 14.49 | E | C |
| ATOM | 9144 | CG1 | ILE | E | 592 | −4.655 | 50.155 | 42.787 | 1.00 | 14.68 | E | C |
| ATOM | 9145 | CD1 | ILE | E | 592 | −3.466 | 50.855 | 43.442 | 1.00 | 11.38 | E | C |
| ATOM | 9146 | C | ILE | E | 592 | −7.251 | 49.314 | 43.867 | 1.00 | 15.99 | E | C |
| ATOM | 9147 | O | ILE | E | 592 | −8.094 | 50.033 | 43.318 | 1.00 | 14.64 | E | O |
| ATOM | 9148 | N | SER | E | 593 | −7.023 | 49.307 | 45.182 | 1.00 | 15.66 | E | N |
| ATOM | 9149 | CA | SER | E | 593 | −7.716 | 50.188 | 46.118 | 1.00 | 14.69 | E | C |
| ATOM | 9150 | CB | SER | E | 593 | −8.514 | 49.376 | 47.127 | 1.00 | 14.32 | E | C |
| ATOM | 9151 | OG | SER | E | 593 | −9.680 | 48.855 | 46.533 | 1.00 | 13.72 | E | O |
| ATOM | 9152 | C | SER | E | 593 | −6.663 | 51.009 | 46.851 | 1.00 | 13.68 | E | C |
| ATOM | 9153 | O | SER | E | 593 | −5.618 | 50.473 | 47.235 | 1.00 | 14.94 | E | O |
| ATOM | 9154 | N | HIS | E | 594 | −6.957 | 52.299 | 47.031 | 1.00 | 12.71 | E | N |
| ATOM | 9155 | CA | HIS | E | 594 | −6.091 | 53.288 | 47.703 | 1.00 | 12.59 | E | C |
| ATOM | 9156 | CB | HIS | E | 594 | −5.357 | 52.683 | 48.917 | 1.00 | 11.82 | E | C |
| ATOM | 9157 | CG | HIS | E | 594 | −6.268 | 52.304 | 50.048 | 1.00 | 11.60 | E | C |
| ATOM | 9158 | CD2 | HIS | E | 594 | −6.473 | 51.118 | 50.668 | 1.00 | 10.62 | E | C |
| ATOM | 9159 | ND1 | HIS | E | 594 | −7.163 | 53.188 | 50.614 | 1.00 | 10.86 | E | N |
| ATOM | 9160 | CE1 | HIS | E | 594 | −7.883 | 52.563 | 51.529 | 1.00 | 8.48 | E | C |
| ATOM | 9161 | NE2 | HIS | E | 594 | −7.484 | 51.306 | 51.581 | 1.00 | 9.56 | E | N |
| ATOM | 9162 | C | HIS | E | 594 | −5.088 | 53.910 | 46.732 | 1.00 | 12.67 | E | C |
| ATOM | 9163 | O | HIS | E | 594 | −5.343 | 54.984 | 46.203 | 1.00 | 13.29 | E | O |
| ATOM | 9164 | N | GLY | E | 595 | −3.958 | 53.249 | 46.503 | 1.00 | 12.49 | E | N |
| ATOM | 9165 | CA | GLY | E | 595 | −2.962 | 53.774 | 45.576 | 1.00 | 12.89 | E | C |
| ATOM | 9166 | C | GLY | E | 595 | −2.269 | 55.079 | 45.937 | 1.00 | 14.80 | E | C |
| ATOM | 9167 | O | GLY | E | 595 | −1.615 | 55.689 | 45.091 | 1.00 | 13.80 | E | O |
| ATOM | 9168 | N | LEU | E | 596 | −2.381 | 55.497 | 47.195 | 1.00 | 16.55 | E | N |
| ATOM | 9169 | CA | LEU | E | 596 | −1.779 | 56.749 | 47.669 | 1.00 | 14.69 | E | C |
| ATOM | 9170 | CB | LEU | E | 596 | −1.991 | 56.891 | 49.180 | 1.00 | 14.99 | E | C |
| ATOM | 9171 | CG | LEU | E | 596 | −3.435 | 57.019 | 49.656 | 1.00 | 15.52 | E | C |
| ATOM | 9172 | CD1 | LEU | E | 596 | −3.467 | 57.046 | 51.178 | 1.00 | 14.67 | E | C |
| ATOM | 9173 | CD2 | LEU | E | 596 | −4.043 | 58.294 | 49.073 | 1.00 | 14.83 | E | C |
| ATOM | 9174 | C | LEU | E | 596 | −0.297 | 56.910 | 47.380 | 1.00 | 14.83 | E | C |
| ATOM | 9175 | O | LEU | E | 596 | 0.152 | 57.972 | 46.940 | 1.00 | 14.34 | E | O |
| ATOM | 9176 | N | ASN | E | 597 | 0.465 | 55.857 | 47.636 | 1.00 | 15.52 | E | N |
| ATOM | 9177 | CA | ASN | E | 597 | 1.898 | 55.906 | 47.428 | 1.00 | 16.77 | E | C |
| ATOM | 9178 | CB | ASN | E | 597 | 2.539 | 54.667 | 48.052 | 1.00 | 15.83 | E | C |
| ATOM | 9179 | CG | ASN | E | 597 | 2.789 | 54.844 | 49.533 | 1.00 | 18.18 | E | C |
| ATOM | 9180 | OD1 | ASN | E | 597 | 2.709 | 55.959 | 50.052 | 1.00 | 19.19 | E | O |
| ATOM | 9181 | ND2 | ASN | E | 597 | 3.089 | 53.750 | 50.224 | 1.00 | 15.54 | E | N |
| ATOM | 9182 | C | ASN | E | 597 | 2.391 | 56.109 | 45.989 | 1.00 | 17.50 | E | C |
| ATOM | 9183 | O | ASN | E | 597 | 3.606 | 56.219 | 45.759 | 1.00 | 15.85 | E | O |
| ATOM | 9184 | N | LEU | E | 598 | 1.475 | 56.168 | 45.021 | 1.00 | 17.75 | E | N |
| ATOM | 9185 | CA | LEU | E | 598 | 1.900 | 56.413 | 43.638 | 1.00 | 17.91 | E | C |
| ATOM | 9186 | CB | LEU | E | 598 | 0.719 | 56.315 | 42.668 | 1.00 | 16.08 | E | C |
| ATOM | 9187 | CG | LEU | E | 598 | 0.286 | 54.889 | 42.316 | 1.00 | 14.70 | E | C |
| ATOM | 9188 | CD1 | LEU | E | 598 | −1.000 | 54.922 | 41.516 | 1.00 | 12.60 | E | C |
| ATOM | 9189 | CD2 | LEU | E | 598 | 1.399 | 54.194 | 41.545 | 1.00 | 12.25 | E | C |
| ATOM | 9190 | C | LEU | E | 598 | 2.483 | 57.826 | 43.610 | 1.00 | 19.27 | E | C |
| ATOM | 9191 | O | LEU | E | 598 | 3.292 | 58.176 | 42.745 | 1.00 | 20.04 | E | O |
| ATOM | 9192 | N | LYS | E | 599 | 2.067 | 58.623 | 44.587 | 1.00 | 19.25 | E | N |
| ATOM | 9193 | CA | LYS | E | 599 | 2.521 | 59.994 | 44.737 | 1.00 | 20.95 | E | C |
| ATOM | 9194 | CB | LYS | E | 599 | 1.848 | 60.636 | 45.950 | 1.00 | 24.30 | E | C |
| ATOM | 9195 | CG | LYS | E | 599 | 0.609 | 61.429 | 45.615 | 1.00 | 29.63 | E | C |
| ATOM | 9196 | CD | LYS | E | 599 | 0.900 | 62.924 | 45.585 | 1.00 | 35.37 | E | C |
| ATOM | 9197 | CE | LYS | E | 599 | 0.234 | 63.604 | 44.388 | 1.00 | 35.81 | E | C |
| ATOM | 9198 | NZ | LYS | E | 599 | 1.161 | 63.703 | 43.223 | 1.00 | 39.20 | E | N |
| ATOM | 9199 | C | LYS | E | 599 | 4.023 | 60.068 | 44.930 | 1.00 | 21.04 | E | C |
| ATOM | 9200 | O | LYS | E | 599 | 4.636 | 61.083 | 44.616 | 1.00 | 20.88 | E | O |
| ATOM | 9201 | N | LYS | E | 600 | 4.610 | 58.997 | 45.457 | 1.00 | 20.93 | E | N |
| ATOM | 9202 | CA | LYS | E | 600 | 6.048 | 58.965 | 45.714 | 1.00 | 21.61 | E | C |
| ATOM | 9203 | CB | LYS | E | 600 | 6.327 | 58.211 | 47.012 | 1.00 | 22.91 | E | C |
| ATOM | 9204 | CG | LYS | E | 600 | 5.586 | 58.738 | 48.229 | 1.00 | 26.96 | E | C |
| ATOM | 9205 | CD | LYS | E | 600 | 5.772 | 57.800 | 49.406 | 1.00 | 29.18 | E | C |
| ATOM | 9206 | CE | LYS | E | 600 | 5.361 | 58.459 | 50.709 | 1.00 | 34.49 | E | C |
| ATOM | 9207 | NZ | LYS | E | 600 | 5.462 | 57.514 | 51.868 | 1.00 | 37.32 | E | N |
| ATOM | 9208 | C | LYS | E | 600 | 6.911 | 58.355 | 44.606 | 1.00 | 20.74 | E | C |
| ATOM | 9209 | O | LYS | E | 600 | 8.134 | 58.354 | 44.714 | 1.00 | 20.29 | E | O |
| ATOM | 9210 | N | SER | E | 601 | 6.283 | 57.830 | 43.556 | 1.00 | 19.17 | E | N |
| ATOM | 9211 | CA | SER | E | 601 | 7.025 | 57.216 | 42.454 | 1.00 | 19.18 | E | C |
| ATOM | 9212 | CB | SER | E | 601 | 6.864 | 55.698 | 42.484 | 1.00 | 17.21 | E | C |
| ATOM | 9213 | OG | SER | E | 601 | 7.676 | 55.096 | 41.497 | 1.00 | 19.02 | E | O |
| ATOM | 9214 | C | SER | E | 601 | 6.551 | 57.735 | 41.102 | 1.00 | 18.80 | E | C |
| ATOM | 9215 | O | SER | E | 601 | 5.485 | 57.346 | 40.619 | 1.00 | 18.40 | E | O |
| ATOM | 9216 | N | PRO | E | 602 | 7.345 | 58.611 | 40.469 | 1.00 | 18.93 | E | N |
| ATOM | 9217 | CD | PRO | E | 602 | 8.651 | 59.104 | 40.943 | 1.00 | 19.27 | E | C |
| ATOM | 9218 | CA | PRO | E | 602 | 6.991 | 59.178 | 39.162 | 1.00 | 18.57 | E | C |
| ATOM | 9219 | CB | PRO | E | 602 | 8.115 | 60.180 | 38.889 | 1.00 | 19.25 | E | C |
| ATOM | 9220 | CG | PRO | E | 602 | 9.267 | 59.674 | 39.696 | 1.00 | 20.36 | E | C |
| ATOM | 9221 | C | PRO | E | 602 | 6.916 | 58.087 | 38.097 | 1.00 | 17.92 | E | C |
| ATOM | 9222 | O | PRO | E | 602 | 6.065 | 58.120 | 37.213 | 1.00 | 18.70 | E | O |
| ATOM | 9223 | N | VAL | E | 603 | 7.814 | 57.116 | 38.200 | 1.00 | 17.85 | E | N |
| ATOM | 9224 | CA | VAL | E | 603 | 7.857 | 56.016 | 37.255 | 1.00 | 17.14 | E | C |
| ATOM | 9225 | CB | VAL | E | 603 | 9.143 | 55.169 | 37.457 | 1.00 | 17.62 | E | C |
| ATOM | 9226 | CG1 | VAL | E | 603 | 9.163 | 53.998 | 36.482 | 1.00 | 16.80 | E | C |
| ATOM | 9227 | CG2 | VAL | E | 603 | 10.379 | 56.039 | 37.247 | 1.00 | 14.00 | E | C |
| ATOM | 9228 | C | VAL | E | 603 | 6.609 | 55.130 | 37.388 | 1.00 | 17.95 | E | C |
| ATOM | 9229 | O | VAL | E | 603 | 5.963 | 54.817 | 36.388 | 1.00 | 18.17 | E | O |
| ATOM | 9230 | N | LEU | E | 604 | 6.255 | 54.743 | 38.613 | 1.00 | 16.37 | E | N |
| ATOM | 9231 | CA | LEU | E | 604 | 5.080 | 53.901 | 38.815 | 1.00 | 15.37 | E | C |
| ATOM | 9232 | CB | LEU | E | 604 | 5.091 | 53.295 | 40.221 | 1.00 | 16.77 | E | C |
| ATOM | 9233 | CG | LEU | E | 604 | 5.948 | 52.035 | 40.404 | 1.00 | 16.69 | E | C |
| ATOM | 9234 | CD1 | LEU | E | 604 | 6.161 | 51.756 | 41.888 | 1.00 | 16.40 | E | C |
| ATOM | 9235 | CD2 | LEU | E | 604 | 5.266 | 50.854 | 39.744 | 1.00 | 15.16 | E | C |
| ATOM | 9236 | C | LEU | E | 604 | 3.776 | 54.667 | 38.584 | 1.00 | 15.63 | E | C |
| ATOM | 9237 | O | LEU | E | 604 | 2.796 | 54.105 | 38.102 | 1.00 | 16.59 | E | O |
| ATOM | 9238 | N | GLN | E | 605 | 3.761 | 55.950 | 38.931 | 1.00 | 13.73 | E | N |
| ATOM | 9239 | CA | GLN | E | 605 | 2.570 | 56.771 | 38.731 | 1.00 | 13.92 | E | C |
| ATOM | 9240 | CB | GLN | E | 605 | 2.764 | 58.144 | 39.376 | 1.00 | 13.06 | E | C |
| ATOM | 9241 | CG | GLN | E | 605 | 1.509 | 59.001 | 39.417 | 1.00 | 11.22 | E | C |
| ATOM | 9242 | CD | GLN | E | 605 | 1.797 | 60.384 | 39.955 | 1.00 | 14.76 | E | C |
| ATOM | 9243 | OE1 | GLN | E | 605 | 2.710 | 60.556 | 40.769 | 1.00 | 16.84 | E | O |
| ATOM | 9244 | NE2 | GLN | E | 605 | 1.030 | 61.377 | 39.512 | 1.00 | 8.39 | E | N |
| ATOM | 9245 | C | GLN | E | 605 | 2.278 | 56.947 | 37.235 | 1.00 | 13.62 | E | C |
| ATOM | 9246 | O | GLN | E | 605 | 1.121 | 56.938 | 36.811 | 1.00 | 12.77 | E | O |
| ATOM | 9247 | N | TYR | E | 606 | 3.339 | 57.113 | 36.447 | 1.00 | 13.16 | E | N |
| ATOM | 9248 | CA | TYR | E | 606 | 3.213 | 57.285 | 34.999 | 1.00 | 13.86 | E | C |
| ATOM | 9249 | CB | TYR | E | 606 | 4.548 | 57.767 | 34.410 | 1.00 | 12.91 | E | C |
| ATOM | 9250 | CG | TYR | E | 606 | 4.452 | 58.296 | 32.992 | 1.00 | 14.13 | E | C |
| ATOM | 9251 | CD1 | TYR | E | 606 | 3.551 | 59.316 | 32.661 | 1.00 | 14.91 | E | C |
| ATOM | 9252 | CE1 | TYR | E | 606 | 3.469 | 59.810 | 31.362 | 1.00 | 15.28 | E | C |
| ATOM | 9253 | CD2 | TYR | E | 606 | 5.270 | 57.783 | 31.983 | 1.00 | 14.06 | E | C |
| ATOM | 9254 | CE2 | TYR | E | 606 | 5.197 | 58.269 | 30.680 | 1.00 | 14.13 | E | C |
| ATOM | 9255 | CZ | TYR | E | 606 | 4.299 | 59.278 | 30.377 | 1.00 | 14.81 | E | C |
| ATOM | 9256 | OH | TYR | E | 606 | 4.231 | 59.758 | 29.091 | 1.00 | 17.15 | E | O |
| ATOM | 9257 | C | TYR | E | 606 | 2.782 | 55.968 | 34.346 | 1.00 | 12.33 | E | C |
| ATOM | 9258 | O | TYR | E | 606 | 1.955 | 55.959 | 33.432 | 1.00 | 12.21 | E | O |
| ATOM | 9259 | N | LEU | E | 607 | 3.335 | 54.859 | 34.831 | 1.00 | 12.30 | E | N |
| ATOM | 9260 | CA | LEU | E | 607 | 2.990 | 53.543 | 34.309 | 1.00 | 12.66 | E | C |
| ATOM | 9261 | CB | LEU | E | 607 | 3.855 | 52.466 | 34.959 | 1.00 | 11.34 | E | C |
| ATOM | 9262 | CG | LEU | E | 607 | 5.269 | 52.346 | 34.391 | 1.00 | 12.39 | E | C |
| ATOM | 9263 | CD1 | LEU | E | 607 | 6.003 | 51.231 | 35.106 | 1.00 | 11.58 | E | C |
| ATOM | 9264 | CD2 | LEU | E | 607 | 5.206 | 52.080 | 32.901 | 1.00 | 12.65 | E | C |
| ATOM | 9265 | C | LEU | E | 607 | 1.522 | 53.246 | 34.570 | 1.00 | 12.77 | E | C |
| ATOM | 9266 | O | LEU | E | 607 | 0.852 | 52.619 | 33.753 | 1.00 | 14.97 | E | O |
| ATOM | 9267 | N | PHE | E | 608 | 1.012 | 53.694 | 35.708 | 1.00 | 13.51 | E | N |
| ATOM | 9268 | CA | PHE | E | 608 | −0.392 | 53.454 | 36.017 | 1.00 | 12.28 | E | C |
| ATOM | 9269 | CB | PHE | E | 608 | −0.686 | 53.785 | 37.483 | 1.00 | 12.39 | E | C |
| ATOM | 9270 | CG | PHE | E | 608 | −0.569 | 52.597 | 38.406 | 1.00 | 12.21 | E | C |
| ATOM | 9271 | CD1 | PHE | E | 608 | 0.663 | 51.986 | 38.619 | 1.00 | 12.37 | E | C |
| ATOM | 9272 | CD2 | PHE | E | 608 | −1.686 | 52.090 | 39.054 | 1.00 | 8.41 | E | C |
| ATOM | 9273 | CE1 | PHE | E | 608 | 0.779 | 50.886 | 39.465 | 1.00 | 12.63 | E | C |
| ATOM | 9274 | CE2 | PHE | E | 608 | −1.583 | 50.993 | 39.899 | 1.00 | 10.56 | E | C |
| ATOM | 9275 | CZ | PHE | E | 608 | −0.351 | 50.389 | 40.107 | 1.00 | 11.34 | E | C |
| ATOM | 9276 | C | PHE | E | 608 | −1.268 | 54.293 | 35.093 | 1.00 | 11.86 | E | C |
| ATOM | 9277 | O | PHE | E | 608 | −2.395 | 53.918 | 34.786 | 1.00 | 13.69 | E | O |
| ATOM | 9278 | N | PHE | E | 609 | −0.747 | 55.437 | 34.661 | 1.00 | 13.25 | E | N |
| ATOM | 9279 | CA | PHE | E | 609 | −1.468 | 56.305 | 33.737 | 1.00 | 13.42 | E | C |
| ATOM | 9280 | CB | PHE | E | 609 | −0.807 | 57.683 | 33.673 | 1.00 | 13.62 | E | C |
| ATOM | 9281 | CG | PHE | E | 609 | −1.268 | 58.512 | 32.504 | 1.00 | 13.51 | E | C |
| ATOM | 9282 | CD1 | PHE | E | 609 | −0.478 | 58.629 | 31.357 | 1.00 | 13.47 | E | C |
| ATOM | 9283 | CD2 | PHE | E | 609 | −2.517 | 59.129 | 32.524 | 1.00 | 9.85 | E | C |
| ATOM | 9284 | CE1 | PHE | E | 609 | −0.932 | 59.345 | 30.244 | 1.00 | 9.27 | E | C |
| ATOM | 9285 | CE2 | PHE | E | 609 | −2.974 | 59.844 | 31.422 | 1.00 | 8.56 | E | C |
| ATOM | 9286 | CZ | PHE | E | 609 | −2.178 | 59.949 | 30.278 | 1.00 | 6.93 | E | C |
| ATOM | 9287 | C | PHE | E | 609 | −1.455 | 55.677 | 32.328 | 1.00 | 13.99 | E | C |
| ATOM | 9288 | O | PHE | E | 609 | −2.491 | 55.555 | 31.678 | 1.00 | 13.11 | E | O |
| ATOM | 9289 | N | LEU | E | 610 | −0.271 | 55.281 | 31.870 | 1.00 | 14.06 | E | N |
| ATOM | 9290 | CA | LEU | E | 610 | −0.119 | 54.675 | 30.553 | 1.00 | 14.57 | E | C |
| ATOM | 9291 | CB | LEU | E | 610 | 1.349 | 54.338 | 30.295 | 1.00 | 14.30 | E | C |
| ATOM | 9292 | CG | LEU | E | 610 | 2.319 | 55.510 | 30.182 | 1.00 | 12.11 | E | C |
| ATOM | 9293 | CD1 | LEU | E | 610 | 3.724 | 54.964 | 30.026 | 1.00 | 12.35 | E | C |
| ATOM | 9294 | CD2 | LEU | E | 610 | 1.946 | 56.390 | 28.995 | 1.00 | 11.35 | E | C |
| ATOM | 9295 | C | LEU | E | 610 | −0.964 | 53.416 | 30.402 | 1.00 | 16.07 | E | C |
| ATOM | 9296 | O | LEU | E | 610 | −1.598 | 53.206 | 29.365 | 1.00 | 19.31 | E | O |
| ATOM | 9297 | N | ALA | E | 611 | −0.968 | 52.571 | 31.428 | 1.00 | 15.95 | E | N |
| ATOM | 9298 | CA | ALA | E | 611 | −1.755 | 51.340 | 31.393 | 1.00 | 14.61 | E | C |
| ATOM | 9299 | CB | ALA | E | 611 | −1.114 | 50.285 | 32.288 | 1.00 | 14.94 | E | C |
| ATOM | 9300 | C | ALA | E | 611 | −3.197 | 51.588 | 31.825 | 1.00 | 13.48 | E | C |
| ATOM | 9301 | O | ALA | E | 611 | −4.023 | 50.682 | 31.788 | 1.00 | 14.87 | E | O |
| ATOM | 9302 | N | GLN | E | 612 | −3.494 | 52.820 | 32.224 | 1.00 | 12.42 | E | N |
| ATOM | 9303 | CA | GLN | E | 612 | −4.831 | 53.199 | 32.678 | 1.00 | 12.54 | E | C |
| ATOM | 9304 | CB | GLN | E | 612 | −5.794 | 53.275 | 31.482 | 1.00 | 12.11 | E | C |
| ATOM | 9305 | CG | GLN | E | 612 | −5.749 | 54.594 | 30.709 | 1.00 | 10.75 | E | C |
| ATOM | 9306 | CD | GLN | E | 612 | −6.023 | 55.810 | 31.584 | 1.00 | 13.92 | E | C |
| ATOM | 9307 | OE1 | GLN | E | 612 | −7.166 | 56.099 | 31.922 | 1.00 | 13.57 | E | O |
| ATOM | 9308 | NE2 | GLN | E | 612 | −4.966 | 56.528 | 31.954 | 1.00 | 15.19 | E | N |
| ATOM | 9309 | C | GLN | E | 612 | −5.396 | 52.243 | 33.750 | 1.00 | 12.25 | E | C |
| ATOM | 9310 | O | GLN | E | 612 | −6.565 | 51.846 | 33.696 | 1.00 | 11.73 | E | O |
| ATOM | 9311 | N | ILE | E | 613 | −4.566 | 51.884 | 34.727 | 1.00 | 11.09 | E | N |
| ATOM | 9312 | CA | ILE | E | 613 | −4.987 | 50.975 | 35.795 | 1.00 | 11.00 | E | C |
| ATOM | 9313 | CB | ILE | E | 613 | −3.762 | 50.498 | 36.622 | 1.00 | 8.41 | E | C |
| ATOM | 9314 | CG2 | ILE | E | 613 | −4.194 | 49.446 | 37.649 | 1.00 | 6.58 | E | C |
| ATOM | 9315 | CG1 | ILE | E | 613 | −2.699 | 49.929 | 35.675 | 1.00 | 6.78 | E | C |
| ATOM | 9316 | CD1 | ILE | E | 613 | −1.454 | 49.399 | 36.354 | 1.00 | 5.89 | E | C |
| ATOM | 9317 | C | ILE | E | 613 | −6.001 | 51.650 | 36.729 | 1.00 | 10.80 | E | C |
| ATOM | 9318 | O | ILE | E | 613 | −5.705 | 52.671 | 37.343 | 1.00 | 12.87 | E | O |
| ATOM | 9319 | N | PRO | E | 614 | −7.218 | 51.089 | 36.840 | 1.00 | 9.37 | E | N |
| ATOM | 9320 | CD | PRO | E | 614 | −7.721 | 49.877 | 36.178 | 1.00 | 7.49 | E | C |
| ATOM | 9321 | CA | PRO | E | 614 | −8.224 | 51.698 | 37.724 | 1.00 | 10.73 | E | C |
| ATOM | 9322 | CB | PRO | E | 614 | −9.482 | 50.858 | 37.493 | 1.00 | 10.43 | E | C |
| ATOM | 9323 | CG | PRO | E | 614 | −9.203 | 50.038 | 36.275 | 1.00 | 9.62 | E | C |
| ATOM | 9324 | C | PRO | E | 614 | −7.802 | 51.689 | 39.200 | 1.00 | 10.57 | E | C |
| ATOM | 9325 | O | PRO | E | 614 | −7.262 | 50.700 | 39.697 | 1.00 | 9.61 | E | O |
| ATOM | 9326 | N | ILE | E | 615 | −8.053 | 52.805 | 39.881 | 1.00 | 11.63 | E | N |
| ATOM | 9327 | CA | ILE | E | 615 | −7.721 | 52.953 | 41.299 | 1.00 | 11.85 | E | C |
| ATOM | 9328 | CB | ILE | E | 615 | −6.585 | 53.989 | 41.511 | 1.00 | 11.27 | E | C |
| ATOM | 9329 | CG2 | ILE | E | 615 | −6.290 | 54.157 | 43.004 | 1.00 | 10.99 | E | C |
| ATOM | 9330 | CG1 | ILE | E | 615 | −5.319 | 53.534 | 40.789 | 1.00 | 9.54 | E | C |
| ATOM | 9331 | CD1 | ILE | E | 615 | −4.398 | 54.679 | 40.394 | 1.00 | 9.58 | E | C |
| ATOM | 9332 | C | ILE | E | 615 | −8.949 | 53.426 | 42.079 | 1.00 | 12.41 | E | C |
| ATOM | 9333 | O | ILE | E | 615 | −9.476 | 54.510 | 41.819 | 1.00 | 13.07 | E | O |
| ATOM | 9334 | N | ALA | E | 616 | −9.422 | 52.600 | 43.011 | 1.00 | 11.73 | E | N |
| ATOM | 9335 | CA | ALA | E | 616 | −10.567 | 52.975 | 43.841 | 1.00 | 12.32 | E | C |
| ATOM | 9336 | CB | ALA | E | 616 | −11.322 | 51.728 | 44.307 | 1.00 | 10.95 | E | C |
| ATOM | 9337 | C | ALA | E | 616 | −9.983 | 53.717 | 45.043 | 1.00 | 11.48 | E | C |
| ATOM | 9338 | O | ALA | E | 616 | −9.233 | 53.132 | 45.832 | 1.00 | 9.91 | E | O |
| ATOM | 9339 | N | MET | E | 617 | −10.306 | 55.002 | 45.166 | 1.00 | 10.91 | E | N |
| ATOM | 9340 | CA | MET | E | 617 | −9.802 | 55.816 | 46.269 | 1.00 | 11.20 | E | C |
| ATOM | 9341 | CB | MET | E | 617 | −9.217 | 57.127 | 45.728 | 1.00 | 11.47 | E | C |
| ATOM | 9342 | CG | MET | E | 617 | −8.238 | 56.966 | 44.565 | 1.00 | 11.90 | E | C |
| ATOM | 9343 | SD | MET | E | 617 | −7.006 | 58.297 | 44.459 | 1.00 | 14.32 | E | S |
| ATOM | 9344 | CE | MET | E | 617 | −7.724 | 59.325 | 43.341 | 1.00 | 19.72 | E | C |
| ATOM | 9345 | C | MET | E | 617 | −10.884 | 56.115 | 47.321 | 1.00 | 12.52 | E | C |
| ATOM | 9346 | O | MET | E | 617 | −12.083 | 56.161 | 47.005 | 1.00 | 11.34 | E | O |
| ATOM | 9347 | N | SER | E | 618 | −10.446 | 56.313 | 48.568 | 1.00 | 13.55 | E | N |
| ATOM | 9348 | CA | SER | E | 618 | −11.333 | 56.598 | 49.702 | 1.00 | 13.29 | E | C |
| ATOM | 9349 | CB | SER | E | 618 | −11.508 | 55.349 | 50.568 | 1.00 | 13.03 | E | C |
| ATOM | 9350 | OG | SER | E | 618 | −11.735 | 54.202 | 49.774 | 1.00 | 17.03 | E | O |
| ATOM | 9351 | C | SER | E | 618 | −10.732 | 57.695 | 50.560 | 1.00 | 13.94 | E | C |
| ATOM | 9352 | O | SER | E | 618 | −10.093 | 57.411 | 51.568 | 1.00 | 15.86 | E | O |
| ATOM | 9353 | N | PRO | E | 619 | −10.906 | 58.963 | 50.160 | 1.00 | 14.32 | E | N |
| ATOM | 9354 | CD | PRO | E | 619 | −11.596 | 59.400 | 48.934 | 1.00 | 13.19 | E | C |
| ATOM | 9355 | CA | PRO | E | 619 | −10.364 | 60.102 | 50.913 | 1.00 | 14.11 | E | C |
| ATOM | 9356 | CB | PRO | E | 619 | −10.749 | 61.316 | 50.062 | 1.00 | 13.84 | E | C |
| ATOM | 9357 | CG | PRO | E | 619 | −10.998 | 60.755 | 48.688 | 1.00 | 13.52 | E | C |
| ATOM | 9358 | C | PRO | E | 619 | −10.831 | 60.240 | 52.365 | 1.00 | 14.36 | E | C |
| ATOM | 9359 | O | PRO | E | 619 | −10.045 | 60.610 | 53.228 | 1.00 | 15.02 | E | O |
| ATOM | 9360 | N | LEU | E | 620 | −12.098 | 59.952 | 52.642 | 1.00 | 14.28 | E | N |
| ATOM | 9361 | CA | LEU | E | 620 | −12.592 | 60.061 | 54.011 | 1.00 | 14.72 | E | C |
| ATOM | 9362 | CB | LEU | E | 620 | −14.112 | 59.891 | 54.054 | 1.00 | 12.81 | E | C |
| ATOM | 9363 | CG | LEU | E | 620 | −14.896 | 61.143 | 53.627 | 1.00 | 12.95 | E | C |
| ATOM | 9364 | CD1 | LEU | E | 620 | −16.385 | 60.858 | 53.661 | 1.00 | 13.00 | E | C |
| ATOM | 9365 | CD2 | LEU | E | 620 | −14.562 | 62.307 | 54.543 | 1.00 | 14.94 | E | C |
| ATOM | 9366 | C | LEU | E | 620 | −11.911 | 59.018 | 54.900 | 1.00 | 16.27 | E | C |
| ATOM | 9367 | O | LEU | E | 620 | −11.518 | 59.315 | 56.031 | 1.00 | 15.95 | E | O |
| ATOM | 9368 | N | SER | E | 621 | −11.757 | 57.803 | 54.382 | 1.00 | 16.18 | E | N |
| ATOM | 9369 | CA | SER | E | 621 | −11.105 | 56.739 | 55.131 | 1.00 | 15.83 | E | C |
| ATOM | 9370 | CB | SER | E | 621 | −11.247 | 55.415 | 54.388 | 1.00 | 16.22 | E | C |
| ATOM | 9371 | OG | SER | E | 621 | −10.277 | 54.482 | 54.820 | 1.00 | 16.32 | E | O |
| ATOM | 9372 | C | SER | E | 621 | −9.625 | 57.071 | 55.348 | 1.00 | 17.98 | E | C |
| ATOM | 9373 | O | SER | E | 621 | −9.103 | 56.896 | 56.449 | 1.00 | 18.18 | E | O |
| ATOM | 9374 | N | ASN | E | 622 | −8.955 | 57.560 | 54.302 | 1.00 | 17.48 | E | N |
| ATOM | 9375 | CA | ASN | E | 622 | −7.543 | 57.929 | 54.398 | 1.00 | 18.13 | E | C |
| ATOM | 9376 | CB | ASN | E | 622 | −7.015 | 58.445 | 53.058 | 1.00 | 16.65 | E | C |
| ATOM | 9377 | CG | ASN | E | 622 | −7.129 | 57.430 | 51.939 | 1.00 | 18.88 | E | C |
| ATOM | 9378 | OD1 | ASN | E | 622 | −7.021 | 57.788 | 50.770 | 1.00 | 19.24 | E | O |
| ATOM | 9379 | ND2 | ASN | E | 622 | −7.337 | 56.168 | 52.285 | 1.00 | 16.28 | E | N |
| ATOM | 9380 | C | ASN | E | 622 | −7.346 | 59.036 | 55.439 | 1.00 | 17.76 | E | C |
| ATOM | 9381 | O | ASN | E | 622 | −6.373 | 59.038 | 56.190 | 1.00 | 17.86 | E | O |
| ATOM | 9382 | N | ASN | E | 623 | −8.272 | 59.984 | 55.453 | 1.00 | 17.79 | E | N |
| ATOM | 9383 | CA | ASN | E | 623 | −8.227 | 61.110 | 56.376 | 1.00 | 22.05 | E | C |
| ATOM | 9384 | CB | ASN | E | 623 | −9.404 | 62.041 | 56.085 | 1.00 | 20.74 | E | C |
| ATOM | 9385 | CG | ASN | E | 623 | −9.542 | 63.157 | 57.104 | 1.00 | 22.23 | E | C |
| ATOM | 9386 | OD1 | ASN | E | 623 | −10.554 | 63.245 | 57.804 | 1.00 | 21.52 | E | O |
| ATOM | 9387 | ND2 | ASN | E | 623 | −8.535 | 64.022 | 57.186 | 1.00 | 19.11 | E | N |
| ATOM | 9388 | C | ASN | E | 623 | −8.266 | 60.656 | 57.835 | 1.00 | 24.12 | E | C |
| ATOM | 9389 | O | ASN | E | 623 | −7.681 | 61.286 | 58.709 | 1.00 | 25.10 | E | O |
| ATOM | 9390 | N | SER | E | 624 | −8.951 | 59.549 | 58.084 | 1.00 | 27.91 | E | N |
| ATOM | 9391 | CA | SER | E | 624 | −9.082 | 59.010 | 59.426 | 1.00 | 32.44 | E | C |
| ATOM | 9392 | CB | SER | E | 624 | −10.469 | 58.393 | 59.592 | 1.00 | 33.24 | E | C |
| ATOM | 9393 | OG | SER | E | 624 | −11.036 | 58.723 | 60.842 | 1.00 | 39.10 | E | O |
| ATOM | 9394 | C | SER | E | 624 | −8.041 | 57.952 | 59.756 | 1.00 | 34.43 | E | C |
| ATOM | 9395 | O | SER | E | 624 | −7.933 | 57.535 | 60.904 | 1.00 | 37.15 | E | O |
| ATOM | 9396 | N | LEU | E | 625 | −7.269 | 57.523 | 58.765 | 1.00 | 35.66 | E | N |
| ATOM | 9397 | CA | LEU | E | 625 | −6.286 | 56.469 | 58.991 | 1.00 | 38.25 | E | C |
| ATOM | 9398 | CB | LEU | E | 625 | −6.710 | 55.214 | 58.212 | 1.00 | 40.82 | E | C |
| ATOM | 9399 | CG | LEU | E | 625 | −7.163 | 53.924 | 58.912 | 1.00 | 42.79 | E | C |
| ATOM | 9400 | CD1 | LEU | E | 625 | −6.944 | 54.006 | 60.406 | 1.00 | 45.12 | E | C |
| ATOM | 9401 | CD2 | LEU | E | 625 | −8.620 | 53.683 | 58.613 | 1.00 | 43.09 | E | C |
| ATOM | 9402 | C | LEU | E | 625 | −4.816 | 56.768 | 58.676 | 1.00 | 37.83 | E | C |
| ATOM | 9403 | O | LEU | E | 625 | −3.942 | 56.452 | 59.481 | 1.00 | 38.55 | E | O |
| ATOM | 9404 | N | PHE | E | 626 | −4.534 | 57.363 | 57.518 | 1.00 | 35.67 | E | N |
| ATOM | 9405 | CA | PHE | E | 626 | −3.145 | 57.620 | 57.140 | 1.00 | 33.62 | E | C |
| ATOM | 9406 | CB | PHE | E | 626 | −2.676 | 56.541 | 56.153 | 1.00 | 33.80 | E | C |
| ATOM | 9407 | CG | PHE | E | 626 | −2.626 | 55.152 | 56.735 | 1.00 | 35.62 | E | C |
| ATOM | 9408 | CD1 | PHE | E | 626 | −1.501 | 54.709 | 57.428 | 1.00 | 35.75 | E | C |
| ATOM | 9409 | CD2 | PHE | E | 626 | −3.701 | 54.276 | 56.574 | 1.00 | 36.96 | E | C |
| ATOM | 9410 | CE1 | PHE | E | 626 | −1.447 | 53.412 | 57.955 | 1.00 | 36.59 | E | C |
| ATOM | 9411 | CE2 | PHE | E | 626 | −3.658 | 52.977 | 57.096 | 1.00 | 36.73 | E | C |
| ATOM | 9412 | CZ | PHE | E | 626 | −2.529 | 52.545 | 57.788 | 1.00 | 37.31 | E | C |
| ATOM | 9413 | C | PHE | E | 626 | −2.799 | 58.984 | 56.540 | 1.00 | 32.21 | E | C |
| ATOM | 9414 | O | PHE | E | 626 | −1.650 | 59.402 | 56.598 | 1.00 | 31.72 | E | O |
| ATOM | 9415 | N | LEU | E | 627 | −3.772 | 59.682 | 55.965 | 1.00 | 31.79 | E | N |
| ATOM | 9416 | CA | LEU | E | 627 | −3.486 | 60.968 | 55.326 | 1.00 | 30.29 | E | C |
| ATOM | 9417 | CB | LEU | E | 627 | −3.233 | 60.742 | 53.834 | 1.00 | 29.51 | E | C |
| ATOM | 9418 | CG | LEU | E | 627 | −2.051 | 61.361 | 53.090 | 1.00 | 29.18 | E | C |
| ATOM | 9419 | CD1 | LEU | E | 627 | −2.445 | 61.506 | 51.630 | 1.00 | 29.00 | E | C |
| ATOM | 9420 | CD2 | LEU | E | 627 | −1.663 | 62.700 | 53.670 | 1.00 | 28.91 | E | C |
| ATOM | 9421 | C | LEU | E | 627 | −4.606 | 61.983 | 55.474 | 1.00 | 29.15 | E | C |
| ATOM | 9422 | O | LEU | E | 627 | −5.752 | 61.690 | 55.156 | 1.00 | 30.23 | E | O |
| ATOM | 9423 | N | GLU | E | 628 | −4.262 | 63.182 | 55.927 | 1.00 | 28.56 | E | N |
| ATOM | 9424 | CA | GLU | E | 628 | −5.234 | 64.260 | 56.114 | 1.00 | 30.09 | E | C |
| ATOM | 9425 | CB | GLU | E | 628 | −4.519 | 65.498 | 56.668 | 1.00 | 32.86 | E | C |
| ATOM | 9426 | CG | GLU | E | 628 | −5.159 | 66.834 | 56.327 | 1.00 | 40.81 | E | C |
| ATOM | 9427 | CD | GLU | E | 628 | −4.222 | 67.999 | 56.593 | 1.00 | 45.01 | E | C |
| ATOM | 9428 | OE1 | GLU | E | 628 | −3.192 | 67.790 | 57.271 | 1.00 | 48.08 | E | O |
| ATOM | 9429 | OE2 | GLU | E | 628 | −4.510 | 69.123 | 56.125 | 1.00 | 48.28 | E | O |
| ATOM | 9430 | C | GLU | E | 628 | −5.947 | 64.592 | 54.795 | 1.00 | 28.27 | E | C |
| ATOM | 9431 | O | GLU | E | 628 | −5.310 | 64.673 | 53.742 | 1.00 | 28.31 | E | O |
| ATOM | 9432 | N | TYR | E | 629 | −7.261 | 64.803 | 54.861 | 1.00 | 24.58 | E | N |
| ATOM | 9433 | CA | TYR | E | 629 | −8.059 | 65.085 | 53.670 | 1.00 | 24.19 | E | C |
| ATOM | 9434 | CB | TYR | E | 629 | −9.449 | 65.606 | 54.049 | 1.00 | 21.18 | E | C |
| ATOM | 9435 | CG | TYR | E | 629 | −10.478 | 65.283 | 52.985 | 1.00 | 20.64 | E | C |
| ATOM | 9436 | CD1 | TYR | E | 629 | −10.621 | 66.087 | 51.851 | 1.00 | 20.98 | E | C |
| ATOM | 9437 | CE1 | TYR | E | 629 | −11.502 | 65.735 | 50.818 | 1.00 | 20.39 | E | C |
| ATOM | 9438 | CD2 | TYR | E | 629 | −11.249 | 64.125 | 53.066 | 1.00 | 20.61 | E | C |
| ATOM | 9439 | CE2 | TYR | E | 629 | −12.132 | 63.766 | 52.041 | 1.00 | 19.59 | E | C |
| ATOM | 9440 | CZ | TYR | E | 629 | −12.249 | 64.571 | 50.920 | 1.00 | 19.07 | E | C |
| ATOM | 9441 | OH | TYR | E | 629 | −13.089 | 64.187 | 49.900 | 1.00 | 20.94 | E | O |
| ATOM | 9442 | C | TYR | E | 629 | −7.452 | 66.024 | 52.629 | 1.00 | 24.63 | E | C |
| ATOM | 9443 | O | TYR | E | 629 | −7.223 | 65.627 | 51.488 | 1.00 | 24.29 | E | O |
| ATOM | 9444 | N | ALA | E | 630 | −7.197 | 67.266 | 53.019 | 1.00 | 25.29 | E | N |
| ATOM | 9445 | CA | ALA | E | 630 | −6.641 | 68.255 | 52.105 | 1.00 | 25.30 | E | C |
| ATOM | 9446 | CB | ALA | E | 630 | −6.451 | 69.581 | 52.837 | 1.00 | 25.32 | E | C |
| ATOM | 9447 | C | ALA | E | 630 | −5.333 | 67.828 | 51.438 | 1.00 | 25.76 | E | C |
| ATOM | 9448 | O | ALA | E | 630 | −4.950 | 68.378 | 50.406 | 1.00 | 28.37 | E | O |
| ATOM | 9449 | N | LYS | E | 631 | −4.654 | 66.844 | 52.016 | 1.00 | 25.06 | E | N |
| ATOM | 9450 | CA | LYS | E | 631 | −3.389 | 66.364 | 51.468 | 1.00 | 24.17 | E | C |
| ATOM | 9451 | CB | LYS | E | 631 | −2.467 | 65.924 | 52.611 | 1.00 | 26.18 | E | C |
| ATOM | 9452 | CG | LYS | E | 631 | −1.502 | 66.993 | 53.100 | 1.00 | 31.48 | E | C |
| ATOM | 9453 | CD | LYS | E | 631 | −2.230 | 68.258 | 53.520 | 1.00 | 37.20 | E | C |
| ATOM | 9454 | CE | LYS | E | 631 | −1.383 | 69.507 | 53.264 | 1.00 | 41.19 | E | C |
| ATOM | 9455 | NZ | LYS | E | 631 | −1.966 | 70.727 | 53.912 | 1.00 | 44.22 | E | N |
| ATOM | 9456 | C | LYS | E | 631 | −3.568 | 65.192 | 50.493 | 1.00 | 21.76 | E | C |
| ATOM | 9457 | O | LYS | E | 631 | −2.595 | 64.699 | 49.924 | 1.00 | 21.51 | E | O |
| ATOM | 9458 | N | ASN | E | 632 | −4.808 | 64.751 | 50.298 | 1.00 | 18.24 | E | N |
| ATOM | 9459 | CA | ASN | E | 632 | −5.083 | 63.617 | 49.417 | 1.00 | 17.34 | E | C |
| ATOM | 9460 | CB | ASN | E | 632 | −6.543 | 63.192 | 49.559 | 1.00 | 15.67 | E | C |
| ATOM | 9461 | CG | ASN | E | 632 | −6.760 | 61.751 | 49.184 | 1.00 | 15.93 | E | C |
| ATOM | 9462 | OD1 | ASN | E | 632 | −6.963 | 60.899 | 50.050 | 1.00 | 14.49 | E | O |
| ATOM | 9463 | ND2 | ASN | E | 632 | −6.718 | 61.461 | 47.882 | 1.00 | 13.92 | E | N |
| ATOM | 9464 | C | ASN | E | 632 | −4.770 | 63.860 | 47.941 | 1.00 | 15.13 | E | C |
| ATOM | 9465 | O | ASN | E | 632 | −5.197 | 64.859 | 47.365 | 1.00 | 15.77 | E | O |
| ATOM | 9466 | N | PRO | E | 633 | −4.028 | 62.935 | 47.308 | 1.00 | 15.98 | E | N |
| ATOM | 9467 | CD | PRO | E | 633 | −3.459 | 61.703 | 47.890 | 1.00 | 16.51 | E | C |
| ATOM | 9468 | CA | PRO | E | 633 | −3.673 | 63.072 | 45.890 | 1.00 | 16.19 | E | C |
| ATOM | 9469 | CB | PRO | E | 633 | −2.535 | 62.072 | 45.708 | 1.00 | 16.63 | E | C |
| ATOM | 9470 | CG | PRO | E | 633 | −2.828 | 61.005 | 46.702 | 1.00 | 15.68 | E | C |
| ATOM | 9471 | C | PRO | E | 633 | −4.822 | 62.790 | 44.929 | 1.00 | 15.42 | E | C |
| ATOM | 9472 | O | PRO | E | 633 | −4.602 | 62.661 | 43.735 | 1.00 | 16.66 | E | O |
| ATOM | 9473 | N | PHE | E | 634 | −6.041 | 62.699 | 45.444 | 1.00 | 16.47 | E | N |
| ATOM | 9474 | CA | PHE | E | 634 | −7.206 | 62.421 | 44.607 | 1.00 | 16.70 | E | C |
| ATOM | 9475 | CB | PHE | E | 634 | −8.491 | 62.433 | 45.452 | 1.00 | 16.03 | E | C |
| ATOM | 9476 | CG | PHE | E | 634 | −9.753 | 62.392 | 44.632 | 1.00 | 17.45 | E | C |
| ATOM | 9477 | CD1 | PHE | E | 634 | −10.479 | 63.550 | 44.384 | 1.00 | 16.89 | E | C |
| ATOM | 9478 | CD2 | PHE | E | 634 | −10.193 | 61.199 | 44.066 | 1.00 | 17.96 | E | C |
| ATOM | 9479 | CE1 | PHE | E | 634 | −11.618 | 63.520 | 43.581 | 1.00 | 17.90 | E | C |
| ATOM | 9480 | CE2 | PHE | E | 634 | −11.333 | 61.162 | 43.258 | 1.00 | 18.06 | E | C |
| ATOM | 9481 | CZ | PHE | E | 634 | −12.044 | 62.323 | 43.017 | 1.00 | 16.27 | E | C |
| ATOM | 9482 | C | PHE | E | 634 | −7.371 | 63.380 | 43.422 | 1.00 | 17.65 | E | C |
| ATOM | 9483 | O | PHE | E | 634 | −7.492 | 62.942 | 42.275 | 1.00 | 17.23 | E | O |
| ATOM | 9484 | N | LEU | E | 635 | −7.386 | 64.679 | 43.694 | 1.00 | 15.42 | E | N |
| ATOM | 9485 | CA | LEU | E | 635 | −7.555 | 65.667 | 42.637 | 1.00 | 14.05 | E | C |
| ATOM | 9486 | CB | LEU | E | 635 | −7.698 | 67.066 | 43.245 | 1.00 | 12.60 | E | C |
| ATOM | 9487 | CG | LEU | E | 635 | −7.853 | 68.236 | 42.270 | 1.00 | 12.58 | E | C |
| ATOM | 9488 | CD1 | LEU | E | 635 | −9.110 | 68.047 | 41.436 | 1.00 | 10.19 | E | C |
| ATOM | 9489 | CD2 | LEU | E | 635 | −7.904 | 69.544 | 43.034 | 1.00 | 9.11 | E | C |
| ATOM | 9490 | C | LEU | E | 635 | −6.402 | 65.654 | 41.635 | 1.00 | 15.28 | E | C |
| ATOM | 9491 | O | LEU | E | 635 | −6.622 | 65.726 | 40.424 | 1.00 | 16.54 | E | O |
| ATOM | 9492 | N | ASP | E | 636 | −5.177 | 65.567 | 42.138 | 1.00 | 13.97 | E | N |
| ATOM | 9493 | CA | ASP | E | 636 | −3.995 | 65.537 | 41.292 | 1.00 | 14.60 | E | C |
| ATOM | 9494 | CB | ASP | E | 636 | −2.742 | 65.403 | 42.154 | 1.00 | 15.01 | E | C |
| ATOM | 9495 | CG | ASP | E | 636 | −1.475 | 65.658 | 41.376 | 1.00 | 15.39 | E | C |
| ATOM | 9496 | OD1 | ASP | E | 636 | −1.391 | 66.711 | 40.714 | 1.00 | 20.10 | E | O |
| ATOM | 9497 | OD2 | ASP | E | 636 | −0.566 | 64.813 | 41.425 | 1.00 | 15.85 | E | O |
| ATOM | 9498 | C | ASP | E | 636 | −4.049 | 64.379 | 40.298 | 1.00 | 14.84 | E | C |
| ATOM | 9499 | O | ASP | E | 636 | −3.780 | 64.555 | 39.111 | 1.00 | 15.95 | E | O |
| ATOM | 9500 | N | PHE | E | 637 | −4.381 | 63.195 | 40.802 | 1.00 | 14.43 | E | N |
| ATOM | 9501 | CA | PHE | E | 637 | −4.484 | 62.000 | 39.978 | 1.00 | 14.09 | E | C |
| ATOM | 9502 | CB | PHE | E | 637 | −4.760 | 60.772 | 40.859 | 1.00 | 12.19 | E | C |
| ATOM | 9503 | CG | PHE | E | 637 | −3.572 | 60.314 | 41.677 | 1.00 | 11.99 | E | C |
| ATOM | 9504 | CD1 | PHE | E | 637 | −2.357 | 60.996 | 41.630 | 1.00 | 11.58 | E | C |
| ATOM | 9505 | CD2 | PHE | E | 637 | −3.669 | 59.184 | 42.488 | 1.00 | 11.51 | E | C |
| ATOM | 9506 | CE1 | PHE | E | 637 | −1.257 | 60.553 | 42.382 | 1.00 | 10.32 | E | C |
| ATOM | 9507 | CE2 | PHE | E | 637 | −2.576 | 58.735 | 43.240 | 1.00 | 9.19 | E | C |
| ATOM | 9508 | CZ | PHE | E | 637 | −1.373 | 59.419 | 43.186 | 1.00 | 10.34 | E | C |
| ATOM | 9509 | C | PHE | E | 637 | −5.616 | 62.172 | 38.964 | 1.00 | 14.80 | E | C |
| ATOM | 9510 | O | PHE | E | 637 | −5.483 | 61.797 | 37.800 | 1.00 | 15.07 | E | O |
| ATOM | 9511 | N | LEU | E | 638 | −6.726 | 62.749 | 39.411 | 1.00 | 15.14 | E | N |
| ATOM | 9512 | CA | LEU | E | 638 | −7.882 | 62.961 | 38.553 | 1.00 | 16.03 | E | C |
| ATOM | 9513 | CB | LEU | E | 638 | −9.059 | 63.494 | 39.368 | 1.00 | 17.14 | E | C |
| ATOM | 9514 | CG | LEU | E | 638 | −10.297 | 63.833 | 38.537 | 1.00 | 18.52 | E | C |
| ATOM | 9515 | CD1 | LEU | E | 638 | −10.919 | 62.554 | 38.018 | 1.00 | 18.53 | E | C |
| ATOM | 9516 | CD2 | LEU | E | 638 | −11.293 | 64.596 | 39.376 | 1.00 | 19.41 | E | C |
| ATOM | 9517 | C | LEU | E | 638 | −7.588 | 63.932 | 37.415 | 1.00 | 16.73 | E | C |
| ATOM | 9518 | O | LEU | E | 638 | −7.963 | 63.692 | 36.268 | 1.00 | 16.31 | E | O |
| ATOM | 9519 | N | GLN | E | 639 | −6.935 | 65.039 | 37.742 | 1.00 | 16.22 | E | N |
| ATOM | 9520 | CA | GLN | E | 639 | −6.591 | 66.041 | 36.739 | 1.00 | 15.56 | E | C |
| ATOM | 9521 | CB | GLN | E | 639 | −5.999 | 67.279 | 37.416 | 1.00 | 13.16 | E | C |
| ATOM | 9522 | CG | GLN | E | 639 | −7.038 | 68.112 | 38.147 | 1.00 | 13.66 | E | C |
| ATOM | 9523 | CD | GLN | E | 639 | −6.436 | 69.303 | 38.856 | 1.00 | 15.38 | E | C |
| ATOM | 9524 | OE1 | GLN | E | 639 | −5.247 | 69.316 | 39.171 | 1.00 | 16.65 | E | O |
| ATOM | 9525 | NE2 | GLN | E | 639 | −7.256 | 70.317 | 39.107 | 1.00 | 15.74 | E | N |
| ATOM | 9526 | C | GLN | E | 639 | −5.602 | 65.485 | 35.715 | 1.00 | 15.62 | E | C |
| ATOM | 9527 | O | GLN | E | 639 | −5.763 | 65.686 | 34.516 | 1.00 | 15.76 | E | O |
| ATOM | 9528 | N | LYS | E | 640 | −4.590 | 64.773 | 36.196 | 1.00 | 15.09 | E | N |
| ATOM | 9529 | CA | LYS | E | 640 | −3.576 | 64.197 | 35.329 | 1.00 | 13.93 | E | C |
| ATOM | 9530 | CB | LYS | E | 640 | −2.442 | 63.603 | 36.172 | 1.00 | 11.75 | E | C |
| ATOM | 9531 | CG | LYS | E | 640 | −1.489 | 64.624 | 36.763 | 1.00 | 9.46 | E | C |
| ATOM | 9532 | CD | LYS | E | 640 | −0.650 | 63.971 | 37.828 | 1.00 | 9.27 | E | C |
| ATOM | 9533 | CE | LYS | E | 640 | 0.389 | 64.902 | 38.399 | 1.00 | 8.06 | E | C |
| ATOM | 9534 | NZ | LYS | E | 640 | 1.133 | 64.171 | 39.473 | 1.00 | 10.87 | E | N |
| ATOM | 9535 | C | LYS | E | 640 | −4.118 | 63.126 | 34.380 | 1.00 | 14.23 | E | C |
| ATOM | 9536 | O | LYS | E | 640 | −3.477 | 62.810 | 33.375 | 1.00 | 14.73 | E | O |
| ATOM | 9537 | N | GLY | E | 641 | −5.274 | 62.552 | 34.703 | 1.00 | 13.30 | E | N |
| ATOM | 9538 | CA | GLY | E | 641 | −5.845 | 61.535 | 33.838 | 1.00 | 13.01 | E | C |
| ATOM | 9539 | C | GLY | E | 641 | −5.774 | 60.084 | 34.296 | 1.00 | 14.17 | E | C |
| ATOM | 9540 | O | GLY | E | 641 | −6.124 | 59.190 | 33.530 | 1.00 | 13.40 | E | O |
| ATOM | 9541 | N | LEU | E | 642 | −5.321 | 59.822 | 35.521 | 1.00 | 14.49 | E | N |
| ATOM | 9542 | CA | LEU | E | 642 | −5.268 | 58.438 | 35.994 | 1.00 | 13.02 | E | C |
| ATOM | 9543 | CB | LEU | E | 642 | −4.550 | 58.336 | 37.348 | 1.00 | 14.54 | E | C |
| ATOM | 9544 | CG | LEU | E | 642 | −3.099 | 58.814 | 37.571 | 1.00 | 15.80 | E | C |
| ATOM | 9545 | CD1 | LEU | E | 642 | −2.276 | 57.661 | 38.095 | 1.00 | 15.37 | E | C |
| ATOM | 9546 | CD2 | LEU | E | 642 | −2.486 | 59.375 | 36.313 | 1.00 | 16.30 | E | C |
| ATOM | 9547 | C | LEU | E | 642 | −6.702 | 57.934 | 36.127 | 1.00 | 10.47 | E | C |
| ATOM | 9548 | O | LEU | E | 642 | −7.614 | 58.712 | 36.376 | 1.00 | 10.63 | E | O |
| ATOM | 9549 | N | MET | E | 643 | −6.896 | 56.634 | 35.949 | 1.00 | 11.31 | E | N |
| ATOM | 9550 | CA | MET | E | 643 | −8.219 | 56.020 | 36.031 | 1.00 | 13.84 | E | C |
| ATOM | 9551 | CB | MET | E | 643 | −8.154 | 54.617 | 35.416 | 1.00 | 16.80 | E | C |
| ATOM | 9552 | CG | MET | E | 643 | −9.335 | 54.263 | 34.535 | 1.00 | 20.09 | E | C |
| ATOM | 9553 | SD | MET | E | 643 | −10.720 | 53.685 | 35.518 | 1.00 | 29.12 | E | S |
| ATOM | 9554 | CE | MET | E | 643 | −11.641 | 52.734 | 34.262 | 1.00 | 25.38 | E | C |
| ATOM | 9555 | C | MET | E | 643 | −8.712 | 55.955 | 37.486 | 1.00 | 13.12 | E | C |
| ATOM | 9556 | O | MET | E | 643 | −8.544 | 54.940 | 38.170 | 1.00 | 12.80 | E | O |
| ATOM | 9557 | N | ILE | E | 644 | −9.362 | 57.027 | 37.930 | 1.00 | 13.45 | E | N |
| ATOM | 9558 | CA | ILE | E | 644 | −9.821 | 57.151 | 39.319 | 1.00 | 14.92 | E | C |
| ATOM | 9559 | CB | ILE | E | 644 | −9.366 | 58.536 | 39.895 | 1.00 | 16.61 | E | C |
| ATOM | 9560 | CG2 | ILE | E | 644 | −9.864 | 58.704 | 41.300 | 1.00 | 15.73 | E | C |
| ATOM | 9561 | CG1 | ILE | E | 644 | −7.845 | 58.681 | 39.817 | 1.00 | 15.85 | E | C |
| ATOM | 9562 | CD1 | ILE | E | 644 | −7.090 | 57.617 | 40.551 | 1.00 | 18.96 | E | C |
| ATOM | 9563 | C | ILE | E | 644 | −11.318 | 57.020 | 39.623 | 1.00 | 14.13 | E | C |
| ATOM | 9564 | O | ILE | E | 644 | −12.156 | 57.544 | 38.897 | 1.00 | 13.24 | E | O |
| ATOM | 9565 | N | SER | E | 645 | −11.646 | 56.323 | 40.707 | 1.00 | 13.86 | E | N |
| ATOM | 9566 | CA | SER | E | 645 | −13.040 | 56.210 | 41.149 | 1.00 | 14.59 | E | C |
| ATOM | 9567 | CB | SER | E | 645 | −13.639 | 54.833 | 40.806 | 1.00 | 15.00 | E | C |
| ATOM | 9568 | OG | SER | E | 645 | −13.180 | 53.802 | 41.663 | 1.00 | 15.62 | E | O |
| ATOM | 9569 | C | SER | E | 645 | −13.081 | 56.467 | 42.674 | 1.00 | 15.36 | E | C |
| ATOM | 9570 | O | SER | E | 645 | −12.073 | 56.300 | 43.368 | 1.00 | 14.37 | E | O |
| ATOM | 9571 | N | LEU | E | 646 | −14.232 | 56.893 | 43.188 | 1.00 | 14.42 | E | N |
| ATOM | 9572 | CA | LEU | E | 646 | −14.366 | 57.178 | 44.612 | 1.00 | 12.48 | E | C |
| ATOM | 9573 | CB | LEU | E | 646 | −15.178 | 58.462 | 44.824 | 1.00 | 10.33 | E | C |
| ATOM | 9574 | CG | LEU | E | 646 | −14.419 | 59.792 | 44.723 | 1.00 | 7.97 | E | C |
| ATOM | 9575 | CD1 | LEU | E | 646 | −15.406 | 60.929 | 44.808 | 1.00 | 7.00 | E | C |
| ATOM | 9576 | CD2 | LEU | E | 646 | −13.375 | 59.922 | 45.833 | 1.00 | 8.34 | E | C |
| ATOM | 9577 | C | LEU | E | 646 | −15.045 | 56.020 | 45.321 | 1.00 | 14.45 | E | C |
| ATOM | 9578 | O | LEU | E | 646 | −15.992 | 55.425 | 44.801 | 1.00 | 13.83 | E | O |
| ATOM | 9579 | N | SER | E | 647 | −14.551 | 55.689 | 46.511 | 1.00 | 15.29 | E | N |
| ATOM | 9580 | CA | SER | E | 647 | −15.134 | 54.601 | 47.287 | 1.00 | 16.19 | E | C |
| ATOM | 9581 | CB | SER | E | 647 | −14.305 | 53.326 | 47.135 | 1.00 | 14.47 | E | C |
| ATOM | 9582 | OG | SER | E | 647 | −12.963 | 53.556 | 47.500 | 1.00 | 19.52 | E | O |
| ATOM | 9583 | C | SER | E | 647 | −15.295 | 54.943 | 48.768 | 1.00 | 16.12 | E | C |
| ATOM | 9584 | O | SER | E | 647 | −14.683 | 55.877 | 49.283 | 1.00 | 14.96 | E | O |
| ATOM | 9585 | N | THR | E | 648 | −16.110 | 54.141 | 49.438 | 1.00 | 16.06 | E | N |
| ATOM | 9586 | CA | THR | E | 648 | −16.443 | 54.309 | 50.844 | 1.00 | 16.46 | E | C |
| ATOM | 9587 | CB | THR | E | 648 | −17.913 | 53.848 | 51.030 | 1.00 | 15.94 | E | C |
| ATOM | 9588 | OG1 | THR | E | 648 | −18.639 | 54.834 | 51.766 | 1.00 | 21.79 | E | O |
| ATOM | 9589 | CG2 | THR | E | 648 | −17.986 | 52.509 | 51.703 | 1.00 | 13.25 | E | C |
| ATOM | 9590 | C | THR | E | 648 | −15.505 | 53.604 | 51.853 | 1.00 | 16.08 | E | C |
| ATOM | 9591 | O | THR | E | 648 | −15.151 | 54.181 | 52.888 | 1.00 | 15.58 | E | O |
| ATOM | 9592 | N | ASP | E | 649 | −15.098 | 52.373 | 51.538 | 1.00 | 15.77 | E | N |
| ATOM | 9593 | CA | ASP | E | 649 | −14.228 | 51.568 | 52.408 | 1.00 | 17.04 | E | C |
| ATOM | 9594 | CB | ASP | E | 649 | −13.050 | 52.400 | 52.923 | 1.00 | 16.87 | E | C |
| ATOM | 9595 | CG | ASP | E | 649 | −11.861 | 51.549 | 53.315 | 1.00 | 16.95 | E | C |
| ATOM | 9596 | OD1 | ASP | E | 649 | −11.908 | 50.311 | 53.112 | 1.00 | 17.81 | E | O |
| ATOM | 9597 | OD2 | ASP | E | 649 | −10.868 | 52.120 | 53.825 | 1.00 | 15.94 | E | O |
| ATOM | 9598 | C | ASP | E | 649 | −15.004 | 50.973 | 53.596 | 1.00 | 16.71 | E | C |
| ATOM | 9599 | O | ASP | E | 649 | −15.304 | 49.780 | 53.594 | 1.00 | 16.24 | E | O |
| ATOM | 9600 | N | ASP | E | 650 | −15.333 | 51.802 | 54.592 | 1.00 | 17.47 | E | N |
| ATOM | 9601 | CA | ASP | E | 650 | −16.080 | 51.352 | 55.781 | 1.00 | 18.25 | E | C |
| ATOM | 9602 | CB | ASP | E | 650 | −15.126 | 51.000 | 56.930 | 1.00 | 18.47 | E | C |
| ATOM | 9603 | CG | ASP | E | 650 | −14.172 | 49.877 | 56.577 | 1.00 | 21.30 | E | C |
| ATOM | 9604 | OD1 | ASP | E | 650 | −13.076 | 50.175 | 56.069 | 1.00 | 25.49 | E | O |
| ATOM | 9605 | OD2 | ASP | E | 650 | −14.505 | 48.695 | 56.800 | 1.00 | 22.09 | E | O |
| ATOM | 9606 | C | ASP | E | 650 | −17.048 | 52.427 | 56.275 | 1.00 | 18.61 | E | C |
| ATOM | 9607 | O | ASP | E | 650 | −16.723 | 53.191 | 57.179 | 1.00 | 18.17 | E | O |
| ATOM | 9608 | N | PRO | E | 651 | −18.260 | 52.482 | 55.700 | 1.00 | 18.46 | E | N |
| ATOM | 9609 | CD | PRO | E | 651 | −18.759 | 51.575 | 54.653 | 1.00 | 17.55 | E | C |
| ATOM | 9610 | CA | PRO | E | 651 | −19.262 | 53.476 | 56.090 | 1.00 | 18.31 | E | C |
| ATOM | 9611 | CB | PRO | E | 651 | −20.523 | 53.042 | 55.345 | 1.00 | 18.15 | E | C |
| ATOM | 9612 | CG | PRO | E | 651 | −20.046 | 52.207 | 54.233 | 1.00 | 17.96 | E | C |
| ATOM | 9613 | C | PRO | E | 651 | −19.494 | 53.562 | 57.588 | 1.00 | 18.94 | E | C |
| ATOM | 9614 | O | PRO | E | 651 | −19.600 | 54.658 | 58.138 | 1.00 | 16.65 | E | O |
| ATOM | 9615 | N | MET | E | 652 | −19.573 | 52.406 | 58.240 | 1.00 | 19.84 | E | N |
| ATOM | 9616 | CA | MET | E | 652 | −19.810 | 52.357 | 59.680 | 1.00 | 21.18 | E | C |
| ATOM | 9617 | CB | MET | E | 652 | −19.833 | 50.910 | 60.165 | 1.00 | 21.38 | E | C |
| ATOM | 9618 | CG | MET | E | 652 | −20.244 | 50.775 | 61.621 | 1.00 | 25.17 | E | C |
| ATOM | 9619 | SD | MET | E | 652 | −20.537 | 49.081 | 62.081 | 1.00 | 29.58 | E | S |
| ATOM | 9620 | CE | MET | E | 652 | −18.889 | 48.438 | 62.095 | 1.00 | 25.06 | E | C |
| ATOM | 9621 | C | MET | E | 652 | −18.781 | 53.141 | 60.486 | 1.00 | 21.50 | E | C |
| ATOM | 9622 | O | MET | E | 652 | −19.129 | 53.821 | 61.449 | 1.00 | 21.76 | E | O |
| ATOM | 9623 | N | GLN | E | 653 | −17.518 | 53.047 | 60.080 | 1.00 | 22.26 | E | N |
| ATOM | 9624 | CA | GLN | E | 653 | −16.426 | 53.736 | 60.761 | 1.00 | 22.83 | E | C |
| ATOM | 9625 | CB | GLN | E | 653 | −15.105 | 52.990 | 60.522 | 1.00 | 24.02 | E | C |
| ATOM | 9626 | CG | GLN | E | 653 | −14.753 | 51.936 | 61.548 | 1.00 | 28.15 | E | C |
| ATOM | 9627 | CD | GLN | E | 653 | −15.557 | 50.666 | 61.363 | 1.00 | 33.90 | E | C |
| ATOM | 9628 | OE1 | GLN | E | 653 | −16.228 | 50.205 | 62.288 | 1.00 | 39.18 | E | O |
| ATOM | 9629 | NE2 | GLN | E | 653 | −15.501 | 50.094 | 60.163 | 1.00 | 35.34 | E | N |
| ATOM | 9630 | C | GLN | E | 653 | −16.222 | 55.196 | 60.339 | 1.00 | 22.03 | E | C |
| ATOM | 9631 | O | GLN | E | 653 | −15.796 | 56.017 | 61.152 | 1.00 | 20.70 | E | O |
| ATOM | 9632 | N | PHE | E | 654 | −16.525 | 55.532 | 59.085 | 1.00 | 21.52 | E | N |
| ATOM | 9633 | CA | PHE | E | 654 | −16.265 | 56.893 | 58.616 | 1.00 | 20.55 | E | C |
| ATOM | 9634 | CB | PHE | E | 654 | −15.248 | 56.851 | 57.467 | 1.00 | 20.01 | E | C |
| ATOM | 9635 | CG | PHE | E | 654 | −14.118 | 55.879 | 57.677 | 1.00 | 19.19 | E | C |
| ATOM | 9636 | CD1 | PHE | E | 654 | −13.994 | 54.761 | 56.869 | 1.00 | 17.02 | E | C |
| ATOM | 9637 | CD2 | PHE | E | 654 | −13.164 | 56.100 | 58.668 | 1.00 | 18.05 | E | C |
| ATOM | 9638 | CE1 | PHE | E | 654 | −12.933 | 53.870 | 57.037 | 1.00 | 18.70 | E | C |
| ATOM | 9639 | CE2 | PHE | E | 654 | −12.101 | 55.218 | 58.846 | 1.00 | 17.91 | E | C |
| ATOM | 9640 | CZ | PHE | E | 654 | −11.984 | 54.098 | 58.026 | 1.00 | 18.38 | E | C |
| ATOM | 9641 | C | PHE | E | 654 | −17.397 | 57.817 | 58.180 | 1.00 | 20.02 | E | C |
| ATOM | 9642 | O | PHE | E | 654 | −17.178 | 59.020 | 58.058 | 1.00 | 21.63 | E | O |
| ATOM | 9643 | N | HIS | E | 655 | −18.596 | 57.302 | 57.947 | 1.00 | 20.42 | E | N |
| ATOM | 9644 | CA | HIS | E | 655 | −19.651 | 58.185 | 57.459 | 1.00 | 22.26 | E | C |
| ATOM | 9645 | CB | HIS | E | 655 | −20.184 | 57.609 | 56.146 | 1.00 | 21.98 | E | C |
| ATOM | 9646 | CG | HIS | E | 655 | −19.102 | 57.335 | 55.145 | 1.00 | 21.91 | E | C |
| ATOM | 9647 | CD2 | HIS | E | 655 | −18.210 | 56.319 | 55.055 | 1.00 | 18.79 | E | C |
| ATOM | 9648 | ND1 | HIS | E | 655 | −18.781 | 58.215 | 54.132 | 1.00 | 22.22 | E | N |
| ATOM | 9649 | CE1 | HIS | E | 655 | −17.737 | 57.754 | 53.467 | 1.00 | 19.71 | E | C |
| ATOM | 9650 | NE2 | HIS | E | 655 | −17.371 | 56.605 | 54.007 | 1.00 | 17.48 | E | N |
| ATOM | 9651 | C | HIS | E | 655 | −20.787 | 58.555 | 58.412 | 1.00 | 24.06 | E | C |
| ATOM | 9652 | O | HIS | E | 655 | −21.149 | 57.787 | 59.298 | 1.00 | 24.76 | E | O |
| ATOM | 9653 | N | PHE | E | 656 | −21.344 | 59.749 | 58.209 | 1.00 | 26.53 | E | N |
| ATOM | 9654 | CA | PHE | E | 656 | −22.412 | 60.277 | 59.055 | 1.00 | 28.52 | E | C |
| ATOM | 9655 | CB | PHE | E | 656 | −22.145 | 61.750 | 59.374 | 1.00 | 28.82 | E | C |
| ATOM | 9656 | CG | PHE | E | 656 | −20.881 | 61.995 | 60.148 | 1.00 | 29.04 | E | C |
| ATOM | 9657 | CD1 | PHE | E | 656 | −19.759 | 62.511 | 59.522 | 1.00 | 30.99 | E | C |
| ATOM | 9658 | CD2 | PHE | E | 656 | −20.820 | 61.734 | 61.510 | 1.00 | 30.96 | E | C |
| ATOM | 9659 | CE1 | PHE | E | 656 | −18.595 | 62.765 | 60.236 | 1.00 | 29.86 | E | C |
| ATOM | 9660 | CE2 | PHE | E | 656 | −19.659 | 61.985 | 62.234 | 1.00 | 30.90 | E | C |
| ATOM | 9661 | CZ | PHE | E | 656 | −18.545 | 62.501 | 61.593 | 1.00 | 31.29 | E | C |
| ATOM | 9662 | C | PHE | E | 656 | −23.835 | 60.177 | 58.522 | 1.00 | 30.96 | E | C |
| ATOM | 9663 | O | PHE | E | 656 | −24.782 | 60.370 | 59.286 | 1.00 | 33.86 | E | O |
| ATOM | 9664 | N | THR | E | 657 | −24.007 | 59.874 | 57.238 | 1.00 | 32.30 | E | N |
| ATOM | 9665 | CA | THR | E | 657 | −25.350 | 59.814 | 56.662 | 1.00 | 32.44 | E | C |
| ATOM | 9666 | CB | THR | E | 657 | −25.469 | 60.768 | 55.466 | 1.00 | 32.23 | E | C |
| ATOM | 9667 | OG1 | THR | E | 657 | −25.242 | 60.034 | 54.256 | 1.00 | 33.84 | E | O |
| ATOM | 9668 | CG2 | THR | E | 657 | −24.441 | 61.892 | 55.571 | 1.00 | 29.66 | E | C |
| ATOM | 9669 | C | THE | E | 657 | −25.799 | 58.435 | 56.200 | 1.00 | 34.27 | E | C |
| ATOM | 9670 | O | THR | E | 657 | −25.040 | 57.467 | 56.276 | 1.00 | 35.83 | E | O |
| ATOM | 9671 | N | LYS | E | 658 | −27.040 | 58.359 | 55.713 | 1.00 | 35.58 | E | N |
| ATOM | 9672 | CA | LYS | E | 658 | −27.614 | 57.102 | 55.228 | 1.00 | 37.57 | E | C |
| ATOM | 9673 | CB | LYS | E | 658 | −29.148 | 57.174 | 55.213 | 1.00 | 40.98 | E | C |
| ATOM | 9674 | CG | LYS | E | 658 | −29.801 | 57.199 | 56.595 | 1.00 | 45.09 | E | C |
| ATOM | 9675 | CD | LYS | E | 658 | −30.280 | 55.806 | 57.027 | 1.00 | 47.86 | E | C |
| ATOM | 9676 | CE | LYS | E | 658 | −30.149 | 55.600 | 58.544 | 1.00 | 47.30 | E | C |
| ATOM | 9677 | NZ | LYS | E | 658 | −29.062 | 54.650 | 58.903 | 1.00 | 44.90 | E | N |
| ATOM | 9678 | C | LYS | E | 658 | −27.119 | 56.791 | 53.821 | 1.00 | 36.53 | E | C |
| ATOM | 9679 | O | LYS | E | 658 | −27.318 | 55.689 | 53.306 | 1.00 | 36.31 | E | O |
| ATOM | 9680 | N | GLU | E | 659 | −26.479 | 57.773 | 53.198 | 1.00 | 34.85 | E | N |
| ATOM | 9681 | CA | GLU | E | 659 | −25.956 | 57.595 | 51.853 | 1.00 | 33.74 | E | C |
| ATOM | 9682 | CB | GLU | E | 659 | −26.738 | 58.472 | 50.878 | 1.00 | 36.10 | E | C |
| ATOM | 9683 | CG | GLU | E | 659 | −28.228 | 58.149 | 50.854 | 1.00 | 40.89 | E | C |
| ATOM | 9684 | CD | GLU | E | 659 | −28.957 | 58.828 | 49.712 | 1.00 | 43.79 | E | C |
| ATOM | 9685 | OE1 | GLU | E | 659 | −28.887 | 58.309 | 48.575 | 1.00 | 45.21 | E | O |
| ATOM | 9686 | OE2 | GLU | E | 659 | −29.599 | 59.877 | 49.950 | 1.00 | 44.82 | E | O |
| ATOM | 9687 | C | GLU | E | 659 | −24.474 | 57.948 | 51.828 | 1.00 | 31.22 | E | C |
| ATOM | 9688 | O | GLU | E | 659 | −24.079 | 59.004 | 51.325 | 1.00 | 30.68 | E | O |
| ATOM | 9689 | N | PRO | E | 660 | −23.633 | 57.060 | 52.385 | 1.00 | 29.08 | E | N |
| ATOM | 9690 | CD | PRO | E | 660 | −24.063 | 55.803 | 53.027 | 1.00 | 27.97 | E | C |
| ATOM | 9691 | CA | PRO | E | 660 | −22.177 | 57.244 | 52.451 | 1.00 | 26.65 | E | C |
| ATOM | 9692 | CB | PRO | E | 660 | −21.672 | 55.976 | 53.150 | 1.00 | 26.92 | E | C |
| ATOM | 9693 | CG | PRO | E | 660 | −22.802 | 55.000 | 53.067 | 1.00 | 29.03 | E | C |
| ATOM | 9694 | C | PRO | E | 660 | −21.460 | 57.498 | 51.123 | 1.00 | 22.55 | E | C |
| ATOM | 9695 | O | PRO | E | 660 | −20.506 | 58.277 | 51.082 | 1.00 | 22.27 | E | O |
| ATOM | 9696 | N | LEU | E | 661 | −21.898 | 56.846 | 50.049 | 1.00 | 20.96 | E | N |
| ATOM | 9697 | CA | LEU | E | 661 | −21.268 | 57.043 | 48.735 | 1.00 | 18.45 | E | C |
| ATOM | 9698 | CB | LEU | E | 661 | −21.821 | 56.050 | 47.707 | 1.00 | 17.68 | E | C |
| ATOM | 9699 | CG | LEU | E | 661 | −20.881 | 55.393 | 46.674 | 1.00 | 18.66 | E | C |
| ATOM | 9700 | CD1 | LEU | E | 661 | −21.505 | 55.471 | 45.292 | 1.00 | 15.61 | E | C |
| ATOM | 9701 | CD2 | LEU | E | 661 | −19.513 | 56.046 | 46.667 | 1.00 | 14.61 | E | C |
| ATOM | 9702 | C | LEU | E | 661 | −21.504 | 58.469 | 48.243 | 1.00 | 17.61 | E | C |
| ATOM | 9703 | O | LEU | E | 661 | −20.580 | 59.119 | 47.757 | 1.00 | 16.91 | E | O |
| ATOM | 9704 | N | MET | E | 662 | −22.741 | 58.947 | 48.372 | 1.00 | 16.79 | E | N |
| ATOM | 9705 | CA | MET | E | 662 | −23.089 | 60.308 | 47.961 | 1.00 | 19.44 | E | C |
| ATOM | 9706 | CB | MET | E | 662 | −24.592 | 60.550 | 48.112 | 1.00 | 21.31 | E | C |
| ATOM | 9707 | CG | MET | E | 662 | −25.452 | 59.795 | 47.098 | 1.00 | 28.27 | E | C |
| ATOM | 9708 | SD | MET | E | 662 | −25.023 | 60.135 | 45.348 | 1.00 | 35.34 | E | S |
| ATOM | 9709 | CE | MET | E | 662 | −25.155 | 61.947 | 45.313 | 1.00 | 31.76 | E | C |
| ATOM | 9710 | C | MET | E | 662 | −22.325 | 61.294 | 48.839 | 1.00 | 19.52 | E | C |
| ATOM | 9711 | O | MET | E | 662 | −21.962 | 62.391 | 48.400 | 1.00 | 19.32 | E | O |
| ATOM | 9712 | N | GLU | E | 663 | −22.088 | 60.888 | 50.084 | 1.00 | 17.05 | E | N |
| ATOM | 9713 | CA | GLU | E | 663 | −21.356 | 61.701 | 51.044 | 1.00 | 15.98 | E | C |
| ATOM | 9714 | CB | GLU | E | 663 | −21.424 | 61.047 | 52.428 | 1.00 | 17.97 | E | C |
| ATOM | 9715 | CG | GLU | E | 663 | −21.028 | 61.940 | 53.585 | 1.00 | 19.35 | E | C |
| ATOM | 9716 | CD | GLU | E | 663 | −21.110 | 61.213 | 54.919 | 1.00 | 21.27 | E | C |
| ATOM | 9717 | OE1 | GLU | E | 663 | −21.993 | 60.330 | 55.048 | 1.00 | 17.97 | E | O |
| ATOM | 9718 | OE2 | GLU | E | 663 | −20.294 | 61.526 | 55.822 | 1.00 | 19.31 | E | O |
| ATOM | 9719 | C | GLU | E | 663 | −19.901 | 61.841 | 50.601 | 1.00 | 14.91 | E | C |
| ATOM | 9720 | O | GLU | E | 663 | −19.353 | 62.942 | 50.622 | 1.00 | 13.60 | E | O |
| ATOM | 9721 | N | GLU | E | 664 | −19.277 | 60.726 | 50.206 | 1.00 | 15.60 | E | N |
| ATOM | 9722 | CA | GLU | E | 664 | −17.888 | 60.753 | 49.742 | 1.00 | 16.01 | E | C |
| ATOM | 9723 | CB | GLU | E | 664 | −17.397 | 59.350 | 49.375 | 1.00 | 17.44 | E | C |
| ATOM | 9724 | CG | GLU | E | 664 | −16.912 | 58.525 | 50.562 | 1.00 | 22.67 | E | C |
| ATOM | 9725 | CD | GLU | E | 664 | −15.414 | 58.629 | 50.824 | 1.00 | 20.41 | E | C |
| ATOM | 9726 | OE1 | GLU | E | 664 | −14.747 | 59.538 | 50.276 | 1.00 | 19.17 | E | O |
| ATOM | 9727 | OE2 | GLU | E | 664 | −14.905 | 57.787 | 51.598 | 1.00 | 24.26 | E | O |
| ATOM | 9728 | C | GLU | E | 664 | −17.752 | 61.652 | 48.520 | 1.00 | 16.10 | E | C |
| ATOM | 9729 | O | GLU | E | 664 | −16.795 | 62.419 | 48.408 | 1.00 | 17.85 | E | O |
| ATOM | 9730 | N | TYR | E | 665 | −18.708 | 61.540 | 47.601 | 1.00 | 14.24 | E | N |
| ATOM | 9731 | CA | TYR | E | 665 | −18.707 | 62.348 | 46.388 | 1.00 | 15.24 | E | C |
| ATOM | 9732 | CB | TYR | E | 665 | −19.830 | 61.904 | 45.443 | 1.00 | 15.54 | E | C |
| ATOM | 9733 | CG | TYR | E | 665 | −19.425 | 60.845 | 44.437 | 1.00 | 16.81 | E | C |
| ATOM | 9734 | CD1 | TYR | E | 665 | −19.443 | 59.494 | 44.773 | 1.00 | 16.22 | E | C |
| ATOM | 9735 | CE1 | TYR | E | 665 | −19.087 | 58.513 | 43.843 | 1.00 | 17.02 | E | C |
| ATOM | 9736 | CD2 | TYR | E | 665 | −19.037 | 61.194 | 43.136 | 1.00 | 17.50 | E | C |
| ATOM | 9737 | CE2 | TYR | E | 665 | −18.679 | 60.216 | 42.194 | 1.00 | 15.94 | E | C |
| ATOM | 9738 | CZ | TYR | E | 665 | −18.706 | 58.882 | 42.560 | 1.00 | 17.24 | E | C |
| ATOM | 9739 | OH | TYR | E | 665 | −18.341 | 57.911 | 41.661 | 1.00 | 18.47 | E | O |
| ATOM | 9740 | C | TYR | E | 665 | −18.903 | 63.816 | 46.723 | 1.00 | 14.64 | E | C |
| ATOM | 9741 | O | TYR | E | 665 | −18.223 | 64.675 | 46.166 | 1.00 | 17.33 | E | O |
| ATOM | 9742 | N | ALA | E | 666 | −19.831 | 64.101 | 47.636 | 1.00 | 13.60 | E | N |
| ATOM | 9743 | CA | ALA | E | 666 | −20.126 | 65.478 | 48.048 | 1.00 | 14.04 | E | C |
| ATOM | 9744 | CB | ALA | E | 666 | −21.317 | 65.493 | 48.996 | 1.00 | 13.84 | E | C |
| ATOM | 9745 | C | ALA | E | 666 | −18.962 | 66.234 | 48.683 | 1.00 | 13.29 | E | C |
| ATOM | 9746 | O | ALA | E | 666 | −18.680 | 67.366 | 48.307 | 1.00 | 14.43 | E | O |
| ATOM | 9747 | N | ILE | E | 667 | −18.280 | 65.630 | 49.648 | 1.00 | 14.70 | E | N |
| ATOM | 9748 | CA | ILE | E | 667 | −17.178 | 66.346 | 50.274 | 1.00 | 15.42 | E | C |
| ATOM | 9749 | CB | ILE | E | 667 | −16.682 | 65.647 | 51.578 | 1.00 | 15.51 | E | C |
| ATOM | 9750 | CG2 | ILE | E | 667 | −16.268 | 64.215 | 51.293 | 1.00 | 17.47 | E | C |
| ATOM | 9751 | CG1 | ILE | E | 667 | −15.500 | 66.419 | 52.165 | 1.00 | 14.94 | E | C |
| ATOM | 9752 | CD1 | ILE | E | 667 | −14.909 | 65.783 | 53.393 | 1.00 | 18.16 | E | C |
| ATOM | 9753 | C | ILE | E | 667 | −16.022 | 66.499 | 49.300 | 1.00 | 15.32 | E | C |
| ATOM | 9754 | O | ILE | E | 667 | −15.314 | 67.508 | 49.323 | 1.00 | 15.34 | E | O |
| ATOM | 9755 | N | ALA | E | 668 | −15.828 | 65.501 | 48.441 | 1.00 | 15.23 | E | N |
| ATOM | 9756 | CA | ALA | E | 668 | −14.747 | 65.567 | 47.463 | 1.00 | 14.64 | E | C |
| ATOM | 9757 | CB | ALA | E | 668 | −14.675 | 64.261 | 46.656 | 1.00 | 14.07 | E | C |
| ATOM | 9758 | C | ALA | E | 668 | −14.996 | 66.755 | 46.538 | 1.00 | 13.02 | E | C |
| ATOM | 9759 | O | ALA | E | 668 | −14.093 | 67.537 | 46.253 | 1.00 | 14.17 | E | O |
| ATOM | 9760 | N | ALA | E | 669 | −16.238 | 66.890 | 46.084 | 1.00 | 13.34 | E | N |
| ATOM | 9761 | CA | ALA | E | 669 | −16.624 | 67.985 | 45.197 | 1.00 | 14.59 | E | C |
| ATOM | 9762 | CB | ALA | E | 669 | −18.058 | 67.796 | 44.724 | 1.00 | 12.11 | E | C |
| ATOM | 9763 | C | ALA | E | 669 | −16.482 | 69.330 | 45.900 | 1.00 | 15.77 | E | C |
| ATOM | 9764 | O | ALA | E | 669 | −16.039 | 70.306 | 45.297 | 1.00 | 15.38 | E | O |
| ATOM | 9765 | N | GLN | E | 670 | −16.854 | 69.376 | 47.176 | 1.00 | 16.57 | E | N |
| ATOM | 9766 | CA | GLN | E | 670 | −16.758 | 70.608 | 47.952 | 1.00 | 17.19 | E | C |
| ATOM | 9767 | CB | GLN | E | 670 | −17.424 | 70.439 | 49.325 | 1.00 | 19.11 | E | C |
| ATOM | 9768 | CG | GLN | E | 670 | −18.839 | 69.898 | 49.280 | 1.00 | 21.72 | E | C |
| ATOM | 9769 | CD | GLN | E | 670 | −19.875 | 70.991 | 49.143 | 1.00 | 25.29 | E | C |
| ATOM | 9770 | OE1 | GLN | E | 670 | −19.585 | 72.082 | 48.646 | 1.00 | 25.90 | E | O |
| ATOM | 9771 | NE2 | GLN | E | 670 | −21.097 | 70.706 | 49.590 | 1.00 | 26.36 | E | N |
| ATOM | 9772 | C | GLN | E | 670 | −15.323 | 71.081 | 48.156 | 1.00 | 16.28 | E | C |
| ATOM | 9773 | O | GLN | E | 670 | −14.976 | 72.190 | 47.751 | 1.00 | 17.79 | E | O |
| ATOM | 9774 | N | VAL | E | 671 | −14.481 | 70.257 | 48.775 | 1.00 | 16.20 | E | N |
| ATOM | 9775 | CA | VAL | E | 671 | −13.111 | 70.694 | 49.015 | 1.00 | 17.58 | E | C |
| ATOM | 9776 | CB | VAL | E | 671 | −12.460 | 69.939 | 50.243 | 1.00 | 17.81 | E | C |
| ATOM | 9777 | CG1 | VAL | E | 671 | −13.502 | 69.135 | 50.987 | 1.00 | 16.65 | E | C |
| ATOM | 9778 | CG2 | VAL | E | 671 | −11.310 | 69.070 | 49.799 | 1.00 | 17.66 | E | C |
| ATOM | 9779 | C | VAL | E | 671 | −12.187 | 70.651 | 47.791 | 1.00 | 17.13 | E | C |
| ATOM | 9780 | O | VAL | E | 671 | −11.283 | 71.476 | 47.671 | 1.00 | 17.53 | E | O |
| ATOM | 9781 | N | PHE | E | 672 | −12.405 | 69.718 | 46.873 | 1.00 | 17.72 | E | N |
| ATOM | 9782 | CA | PHE | E | 672 | −11.545 | 69.662 | 45.694 | 1.00 | 18.54 | E | C |
| ATOM | 9783 | CB | PHE | E | 672 | −11.342 | 68.219 | 45.252 | 1.00 | 17.87 | E | C |
| ATOM | 9784 | CG | PHE | E | 672 | −10.467 | 67.440 | 46.183 | 1.00 | 20.08 | E | C |
| ATOM | 9785 | CD1 | PHE | E | 672 | −9.190 | 67.894 | 46.494 | 1.00 | 18.94 | E | C |
| ATOM | 9786 | CD2 | PHE | E | 672 | −10.930 | 66.277 | 46.792 | 1.00 | 20.80 | E | C |
| ATOM | 9787 | CE1 | PHE | E | 672 | −8.390 | 67.205 | 47.398 | 1.00 | 20.83 | E | C |
| ATOM | 9788 | CE2 | PHE | E | 672 | −10.132 | 65.581 | 47.700 | 1.00 | 19.21 | E | C |
| ATOM | 9789 | CZ | PHE | E | 672 | −8.864 | 66.046 | 48.003 | 1.00 | 19.91 | E | C |
| ATOM | 9790 | C | PHE | E | 672 | −12.089 | 70.503 | 44.551 | 1.00 | 18.57 | E | C |
| ATOM | 9791 | O | PHE | E | 672 | −11.447 | 70.635 | 43.516 | 1.00 | 17.48 | E | O |
| ATOM | 9792 | N | LYS | E | 673 | −13.269 | 71.082 | 44.766 | 1.00 | 19.75 | E | N |
| ATOM | 9793 | CA | LYS | E | 673 | −13.934 | 71.951 | 43.794 | 1.00 | 19.87 | E | C |
| ATOM | 9794 | CB | LYS | E | 673 | −13.163 | 73.272 | 43.657 | 1.00 | 22.69 | E | C |
| ATOM | 9795 | CG | LYS | E | 673 | −13.727 | 74.400 | 44.520 | 1.00 | 25.17 | E | C |
| ATOM | 9796 | CD | LYS | E | 673 | −12.641 | 75.295 | 45.100 | 1.00 | 28.59 | E | C |
| ATOM | 9797 | CE | LYS | E | 673 | −11.362 | 74.510 | 45.421 | 1.00 | 33.74 | E | C |
| ATOM | 9798 | NZ | LYS | E | 673 | −10.306 | 75.328 | 46.121 | 1.00 | 34.51 | E | N |
| ATOM | 9799 | C | LYS | E | 673 | −14.121 | 71.309 | 42.422 | 1.00 | 19.80 | E | C |
| ATOM | 9800 | O | LYS | E | 673 | −13.711 | 71.860 | 41.396 | 1.00 | 18.40 | E | O |
| ATOM | 9801 | N | LEU | E | 674 | −14.758 | 70.146 | 42.419 | 1.00 | 17.43 | E | N |
| ATOM | 9802 | CA | LEU | E | 674 | −15.029 | 69.392 | 41.197 | 1.00 | 18.02 | E | C |
| ATOM | 9803 | CB | LEU | E | 674 | −15.298 | 67.922 | 41.544 | 1.00 | 17.45 | E | C |
| ATOM | 9804 | CG | LEU | E | 674 | −14.157 | 66.901 | 41.616 | 1.00 | 16.29 | E | C |
| ATOM | 9805 | CD1 | LEU | E | 674 | −12.825 | 67.577 | 41.862 | 1.00 | 14.68 | E | C |
| ATOM | 9806 | CD2 | LEU | E | 674 | −14.482 | 65.908 | 42.723 | 1.00 | 16.40 | E | C |
| ATOM | 9807 | C | LEU | E | 674 | −16.248 | 69.937 | 40.452 | 1.00 | 17.17 | E | C |
| ATOM | 9808 | O | LEU | E | 674 | −17.243 | 70.306 | 41.070 | 1.00 | 15.85 | E | O |
| ATOM | 9809 | N | SER | E | 675 | −16.174 | 69.980 | 39.123 | 1.00 | 16.97 | E | N |
| ATOM | 9810 | CA | SER | E | 675 | −17.302 | 70.437 | 38.307 | 1.00 | 15.83 | E | C |
| ATOM | 9811 | CB | SER | E | 675 | −16.833 | 70.814 | 36.893 | 1.00 | 17.79 | E | C |
| ATOM | 9812 | OG | SER | E | 675 | −16.331 | 69.681 | 36.193 | 1.00 | 17.96 | E | O |
| ATOM | 9813 | C | SER | E | 675 | −18.225 | 69.230 | 38.232 | 1.00 | 15.24 | E | C |
| ATOM | 9814 | O | SER | E | 675 | −17.827 | 68.143 | 38.635 | 1.00 | 14.51 | E | O |
| ATOM | 9815 | N | THR | E | 676 | −19.448 | 69.390 | 37.734 | 1.00 | 16.49 | E | N |
| ATOM | 9816 | CA | THR | E | 676 | −20.329 | 68.228 | 37.653 | 1.00 | 17.32 | E | C |
| ATOM | 9817 | CB | THR | E | 676 | −21.821 | 68.619 | 37.453 | 1.00 | 18.82 | E | C |
| ATOM | 9818 | OG1 | THR | E | 676 | −22.303 | 68.075 | 36.221 | 1.00 | 24.47 | E | O |
| ATOM | 9819 | CG2 | THR | E | 676 | −21.998 | 70.112 | 37.462 | 1.00 | 19.93 | E | C |
| ATOM | 9820 | C | THR | E | 676 | −19.857 | 67.281 | 36.539 | 1.00 | 16.45 | E | C |
| ATOM | 9821 | O | THR | E | 676 | −20.208 | 66.103 | 36.526 | 1.00 | 18.11 | E | O |
| ATOM | 9822 | N | CYS | E | 677 | −19.041 | 67.788 | 35.620 | 1.00 | 14.27 | E | N |
| ATOM | 9823 | CA | CYS | E | 677 | −18.501 | 66.949 | 34.556 | 1.00 | 14.15 | E | C |
| ATOM | 9824 | CB | CYS | E | 677 | −17.908 | 67.799 | 33.419 | 1.00 | 14.67 | E | C |
| ATOM | 9825 | SG | CYS | E | 677 | −17.208 | 66.820 | 32.051 | 1.00 | 16.06 | E | S |
| ATOM | 9826 | C | CYS | E | 677 | −17.404 | 66.102 | 35.188 | 1.00 | 14.75 | E | C |
| ATOM | 9827 | O | CYS | E | 677 | −17.217 | 64.939 | 34.825 | 1.00 | 15.69 | E | O |
| ATOM | 9828 | N | ASP | E | 678 | −16.677 | 66.698 | 36.136 | 1.00 | 14.75 | E | N |
| ATOM | 9829 | CA | ASP | E | 678 | −15.608 | 66.004 | 36.858 | 1.00 | 13.42 | E | C |
| ATOM | 9830 | CB | ASP | E | 678 | −14.927 | 66.951 | 37.851 | 1.00 | 15.43 | E | C |
| ATOM | 9831 | CG | ASP | E | 678 | −14.024 | 67.970 | 37.181 | 1.00 | 17.69 | E | C |
| ATOM | 9832 | OD1 | ASP | E | 678 | −13.513 | 67.691 | 36.077 | 1.00 | 19.63 | E | O |
| ATOM | 9833 | OD2 | ASP | E | 678 | −13.815 | 69.054 | 37.769 | 1.00 | 18.18 | E | O |
| ATOM | 9834 | C | ASP | E | 678 | −16.237 | 64.856 | 37.647 | 1.00 | 14.19 | E | C |
| ATOM | 9835 | O | ASP | E | 678 | −15.717 | 63.745 | 37.677 | 1.00 | 14.49 | E | O |
| ATOM | 9836 | N | MET | E | 679 | −17.366 | 65.147 | 38.286 | 1.00 | 14.20 | E | N |
| ATOM | 9837 | CA | MET | E | 679 | −18.085 | 64.169 | 39.090 | 1.00 | 16.03 | E | C |
| ATOM | 9838 | CB | MET | E | 679 | −19.220 | 64.856 | 39.848 | 1.00 | 16.08 | E | C |
| ATOM | 9839 | CG | MET | E | 679 | −18.756 | 65.842 | 40.898 | 1.00 | 18.89 | E | C |
| ATOM | 9840 | SD | MET | E | 679 | −20.167 | 66.475 | 41.837 | 1.00 | 28.17 | E | S |
| ATOM | 9841 | CE | MET | E | 679 | −20.222 | 68.158 | 41.264 | 1.00 | 24.74 | E | C |
| ATOM | 9842 | C | MET | E | 679 | −18.664 | 63.033 | 38.258 | 1.00 | 16.77 | E | C |
| ATOM | 9843 | O | MET | E | 679 | −18.636 | 61.877 | 38.672 | 1.00 | 17.71 | E | O |
| ATOM | 9844 | N | CYS | E | 680 | −19.205 | 63.361 | 37.091 | 1.00 | 16.78 | E | N |
| ATOM | 9845 | CA | CYS | E | 680 | −19.792 | 62.339 | 36.237 | 1.00 | 15.76 | E | C |
| ATOM | 9846 | CB | CYS | E | 680 | −20.687 | 62.992 | 35.188 | 1.00 | 16.70 | E | C |
| ATOM | 9847 | SG | CYS | E | 680 | −22.178 | 63.737 | 35.894 | 1.00 | 23.02 | E | S |
| ATOM | 9848 | C | CYS | E | 680 | −18.728 | 61.467 | 35.580 | 1.00 | 14.63 | E | C |
| ATOM | 9849 | O | CYS | E | 680 | −19.001 | 60.324 | 35.201 | 1.00 | 16.44 | E | O |
| ATOM | 9850 | N | GLU | E | 681 | −17.516 | 61.999 | 35.450 | 1.00 | 14.01 | E | N |
| ATOM | 9851 | CA | GLU | E | 681 | −16.426 | 61.228 | 34.862 | 1.00 | 12.57 | E | C |
| ATOM | 9852 | CB | GLU | E | 681 | −15.245 | 62.138 | 34.482 | 1.00 | 11.30 | E | C |
| ATOM | 9853 | CG | GLU | E | 681 | −14.201 | 61.425 | 33.617 | 1.00 | 13.89 | E | C |
| ATOM | 9854 | CD | GLU | E | 681 | −12.961 | 62.263 | 33.308 | 1.00 | 14.84 | E | C |
| ATOM | 9855 | OE1 | GLU | E | 681 | −12.882 | 63.429 | 33.743 | 1.00 | 13.34 | E | O |
| ATOM | 9856 | OE2 | GLU | E | 681 | −12.054 | 61.740 | 32.621 | 1.00 | 18.24 | E | O |
| ATOM | 9857 | C | GLU | E | 681 | −15.977 | 60.177 | 35.886 | 1.00 | 12.97 | E | C |
| ATOM | 9858 | O | GLU | E | 681 | −15.676 | 59.037 | 35.536 | 1.00 | 14.45 | E | O |
| ATOM | 9859 | N | VAL | E | 682 | −15.934 | 60.565 | 37.156 | 1.00 | 12.23 | E | N |
| ATOM | 9860 | CA | VAL | E | 682 | −15.531 | 59.641 | 38.212 | 1.00 | 11.93 | E | C |
| ATOM | 9861 | CB | VAL | E | 682 | −15.429 | 60.358 | 39.583 | 1.00 | 11.18 | E | C |
| ATOM | 9862 | CG1 | VAL | E | 682 | −15.361 | 59.322 | 40.712 | 1.00 | 9.59 | E | C |
| ATOM | 9863 | CG2 | VAL | E | 682 | −14.193 | 61.259 | 39.603 | 1.00 | 8.14 | E | C |
| ATOM | 9864 | C | VAL | E | 682 | −16.558 | 58.509 | 38.300 | 1.00 | 11.59 | E | C |
| ATOM | 9865 | O | VAL | E | 682 | −16.199 | 57.336 | 38.416 | 1.00 | 14.08 | E | O |
| ATOM | 9866 | N | ALA | E | 683 | −17.834 | 58.873 | 38.231 | 1.00 | 9.96 | E | N |
| ATOM | 9867 | CA | ALA | E | 683 | −18.924 | 57.907 | 38.285 | 1.00 | 11.15 | E | C |
| ATOM | 9868 | CB | ALA | E | 683 | −20.253 | 58.632 | 38.190 | 1.00 | 10.80 | E | C |
| ATOM | 9869 | C | ALA | E | 683 | −18.814 | 56.882 | 37.164 | 1.00 | 11.65 | E | C |
| ATOM | 9870 | O | ALA | E | 683 | −18.987 | 55.687 | 37.381 | 1.00 | 12.68 | E | O |
| ATOM | 9871 | N | ARG | E | 684 | −18.534 | 57.363 | 35.959 | 1.00 | 14.02 | E | N |
| ATOM | 9872 | CA | ARG | E | 684 | −18.400 | 56.491 | 34.797 | 1.00 | 14.79 | E | C |
| ATOM | 9873 | CB | ARG | E | 684 | −18.155 | 57.328 | 33.534 | 1.00 | 15.79 | E | C |
| ATOM | 9874 | CG | ARG | E | 684 | −17.908 | 56.520 | 32.275 | 1.00 | 12.93 | E | C |
| ATOM | 9875 | CD | ARG | E | 684 | −17.962 | 57.416 | 31.041 | 1.00 | 15.86 | E | C |
| ATOM | 9876 | NE | ARG | E | 684 | −17.995 | 56.634 | 29.812 | 1.00 | 17.69 | E | N |
| ATOM | 9877 | CZ | ARG | E | 684 | −16.918 | 56.139 | 29.214 | 1.00 | 17.28 | E | C |
| ATOM | 9878 | NH1 | ARG | E | 684 | −15.717 | 56.350 | 29.738 | 1.00 | 16.00 | E | N |
| ATOM | 9879 | NH2 | ARG | E | 684 | −17.045 | 55.419 | 28.105 | 1.00 | 17.35 | E | N |
| ATOM | 9880 | C | ARG | E | 684 | −17.237 | 55.545 | 35.028 | 1.00 | 13.55 | E | C |
| ATOM | 9881 | O | ARG | E | 684 | −17.328 | 54.351 | 34.757 | 1.00 | 15.79 | E | O |
| ATOM | 9882 | N | ASN | E | 685 | −16.134 | 56.086 | 35.526 | 1.00 | 14.80 | E | N |
| ATOM | 9883 | CA | ASN | E | 685 | −14.956 | 55.273 | 35.808 | 1.00 | 14.74 | E | C |
| ATOM | 9884 | CB | ASN | E | 685 | −13.861 | 56.130 | 36.446 | 1.00 | 14.74 | E | C |
| ATOM | 9885 | CG | ASN | E | 685 | −13.154 | 57.014 | 35.443 | 1.00 | 16.55 | E | C |
| ATOM | 9886 | OD1 | ASN | E | 685 | −13.469 | 57.000 | 34.254 | 1.00 | 16.76 | E | O |
| ATOM | 9887 | ND2 | ASN | E | 685 | −12.189 | 57.788 | 35.918 | 1.00 | 15.84 | E | N |
| ATOM | 9888 | C | ASN | E | 685 | −15.304 | 54.134 | 36.765 | 1.00 | 15.02 | E | C |
| ATOM | 9889 | O | ASN | E | 685 | −14.837 | 53.007 | 36.596 | 1.00 | 15.08 | E | O |
| ATOM | 9890 | N | SER | E | 686 | −16.124 | 54.430 | 37.772 | 1.00 | 14.37 | E | N |
| ATOM | 9891 | CA | SER | E | 686 | −16.495 | 53.418 | 38.757 | 1.00 | 14.13 | E | C |
| ATOM | 9892 | CB | SER | E | 686 | −17.273 | 54.060 | 39.920 | 1.00 | 11.58 | E | C |
| ATOM | 9893 | OG | SER | E | 686 | −18.647 | 54.259 | 39.637 | 1.00 | 11.10 | E | O |
| ATOM | 9894 | C | SER | E | 686 | −17.281 | 52.275 | 38.129 | 1.00 | 14.14 | E | C |
| ATOM | 9895 | O | SER | E | 686 | −17.085 | 51.115 | 38.491 | 1.00 | 15.61 | E | O |
| ATOM | 9896 | N | VAL | E | 687 | −18.156 | 52.591 | 37.176 | 1.00 | 14.64 | E | N |
| ATOM | 9897 | CA | VAL | E | 687 | −18.935 | 51.554 | 36.504 | 1.00 | 13.38 | E | C |
| ATOM | 9898 | CB | VAL | E | 687 | −20.047 | 52.151 | 35.627 | 1.00 | 13.66 | E | C |
| ATOM | 9899 | CG1 | VAL | E | 687 | −20.834 | 51.026 | 34.959 | 1.00 | 14.35 | E | C |
| ATOM | 9900 | CG2 | VAL | E | 687 | −20.979 | 53.014 | 36.476 | 1.00 | 11.30 | E | C |
| ATOM | 9901 | C | VAL | E | 687 | −18.024 | 50.700 | 35.628 | 1.00 | 13.19 | E | C |
| ATOM | 9902 | O | VAL | E | 687 | −18.151 | 49.476 | 35.591 | 1.00 | 13.63 | E | O |
| ATOM | 9903 | N | LEU | E | 688 | −17.102 | 51.349 | 34.927 | 1.00 | 12.80 | E | N |
| ATOM | 9904 | CA | LEU | E | 688 | −16.162 | 50.637 | 34.064 | 1.00 | 12.77 | E | C |
| ATOM | 9905 | CB | LEU | E | 688 | −15.276 | 51.638 | 33.297 | 1.00 | 10.68 | E | C |
| ATOM | 9906 | CG | LEU | E | 688 | −15.918 | 52.476 | 32.179 | 1.00 | 12.03 | E | C |
| ATOM | 9907 | CD1 | LEU | E | 688 | −14.946 | 53.545 | 31.680 | 1.00 | 6.12 | E | C |
| ATOM | 9908 | CD2 | LEU | E | 688 | −16.327 | 51.565 | 31.043 | 1.00 | 10.10 | E | C |
| ATOM | 9909 | C | LEU | E | 688 | −15.266 | 49.699 | 34.883 | 1.00 | 14.03 | E | C |
| ATOM | 9910 | O | LEU | E | 688 | −14.961 | 48.580 | 34.462 | 1.00 | 14.20 | E | O |
| ATOM | 9911 | N | GLN | E | 689 | −14.848 | 50.168 | 36.055 | 1.00 | 15.10 | E | N |
| ATOM | 9912 | CA | GLN | E | 689 | −13.970 | 49.410 | 36.939 | 1.00 | 14.15 | E | C |
| ATOM | 9913 | CB | GLN | E | 689 | −13.402 | 50.347 | 38.004 | 1.00 | 13.50 | E | C |
| ATOM | 9914 | CG | GLN | E | 689 | −12.649 | 49.635 | 39.109 | 1.00 | 11.88 | E | C |
| ATOM | 9915 | CD | GLN | E | 689 | −11.936 | 50.594 | 40.037 | 1.00 | 12.38 | E | C |
| ATOM | 9916 | OE1 | GLN | E | 689 | −11.071 | 50.192 | 40.809 | 1.00 | 14.00 | E | O |
| ATOM | 9917 | NE2 | GLN | E | 689 | −12.298 | 51.868 | 39.971 | 1.00 | 12.87 | E | N |
| ATOM | 9918 | C | GLN | E | 689 | −14.603 | 48.198 | 37.638 | 1.00 | 15.52 | E | C |
| ATOM | 9919 | O | GLN | E | 689 | −13.970 | 47.144 | 37.762 | 1.00 | 15.48 | E | O |
| ATOM | 9920 | N | CYS | E | 690 | −15.849 | 48.343 | 38.079 | 1.00 | 16.31 | E | N |
| ATOM | 9921 | CA | CYS | E | 690 | −16.533 | 47.283 | 38.819 | 1.00 | 17.59 | E | C |
| ATOM | 9922 | CB | CYS | E | 690 | −17.852 | 47.815 | 39.377 | 1.00 | 16.89 | E | C |
| ATOM | 9923 | SG | CYS | E | 690 | −19.156 | 47.978 | 38.165 | 1.00 | 18.26 | E | S |
| ATOM | 9924 | C | CYS | E | 690 | −16.779 | 45.963 | 38.100 | 1.00 | 18.42 | E | C |
| ATOM | 9925 | O | CYS | E | 690 | −16.483 | 45.819 | 36.915 | 1.00 | 20.31 | E | O |
| ATOM | 9926 | N | GLY | E | 691 | −17.323 | 45.001 | 38.842 | 1.00 | 18.54 | E | N |
| ATOM | 9927 | CA | GLY | E | 691 | −17.597 | 43.684 | 38.301 | 1.00 | 17.38 | E | C |
| ATOM | 9928 | C | GLY | E | 691 | −19.036 | 43.426 | 37.882 | 1.00 | 18.87 | E | C |
| ATOM | 9929 | O | GLY | E | 691 | −19.439 | 42.269 | 37.724 | 1.00 | 20.69 | E | O |
| ATOM | 9930 | N | ILE | E | 692 | −19.815 | 44.488 | 37.701 | 1.00 | 17.36 | E | N |
| ATOM | 9931 | CA | ILE | E | 692 | −21.200 | 44.353 | 37.274 | 1.00 | 17.16 | E | C |
| ATOM | 9932 | CB | ILE | E | 692 | −21.868 | 45.740 | 37.195 | 1.00 | 16.98 | E | C |
| ATOM | 9933 | CG2 | ILE | E | 692 | −23.144 | 45.677 | 36.366 | 1.00 | 16.95 | E | C |
| ATOM | 9934 | CG1 | ILE | E | 692 | −22.181 | 46.231 | 38.612 | 1.00 | 17.39 | E | C |
| ATOM | 9935 | CD1 | ILE | E | 692 | −22.941 | 47.557 | 38.669 | 1.00 | 14.76 | E | C |
| ATOM | 9936 | C | ILE | E | 692 | −21.227 | 43.665 | 35.899 | 1.00 | 17.99 | E | C |
| ATOM | 9937 | O | ILE | E | 692 | −20.252 | 43.740 | 35.153 | 1.00 | 16.82 | E | O |
| ATOM | 9938 | N | SER | E | 693 | −22.331 | 42.994 | 35.571 | 1.00 | 19.22 | E | N |
| ATOM | 9939 | CA | SER | E | 693 | −22.453 | 42.282 | 34.292 | 1.00 | 20.63 | E | C |
| ATOM | 9940 | CB | SER | E | 693 | −23.756 | 41.473 | 34.255 | 1.00 | 19.74 | E | C |
| ATOM | 9941 | OG | SER | E | 693 | −24.879 | 42.309 | 34.021 | 1.00 | 23.53 | E | O |
| ATOM | 9942 | C | SER | E | 693 | −22.373 | 43.180 | 33.050 | 1.00 | 21.52 | E | C |
| ATOM | 9943 | O | SER | E | 693 | −22.661 | 44.381 | 33.104 | 1.00 | 21.09 | E | O |
| ATOM | 9944 | N | HIS | E | 694 | −21.972 | 42.580 | 31.932 | 1.00 | 23.53 | E | N |
| ATOM | 9945 | CA | HIS | E | 694 | −21.843 | 43.302 | 30.669 | 1.00 | 25.76 | E | C |
| ATOM | 9946 | CB | HIS | E | 694 | −21.301 | 42.384 | 29.574 | 1.00 | 26.59 | E | C |
| ATOM | 9947 | CG | HIS | E | 694 | −21.226 | 43.041 | 28.231 | 1.00 | 27.75 | E | C |
| ATOM | 9948 | CD2 | HIS | E | 694 | −20.271 | 43.822 | 27.674 | 1.00 | 27.76 | E | C |
| ATOM | 9949 | ND1 | HIS | E | 694 | −22.246 | 42.965 | 27.307 | 1.00 | 29.74 | E | N |
| ATOM | 9950 | CE1 | HIS | E | 694 | −21.923 | 43.673 | 26.239 | 1.00 | 28.79 | E | C |
| ATOM | 9951 | NE2 | HIS | E | 694 | −20.730 | 44.203 | 26.437 | 1.00 | 28.81 | E | N |
| ATOM | 9952 | C | HIS | E | 694 | −23.165 | 43.889 | 30.203 | 1.00 | 26.49 | E | C |
| ATOM | 9953 | O | HIS | E | 694 | −23.224 | 45.039 | 29.776 | 1.00 | 26.64 | E | O |
| ATOM | 9954 | N | GLU | E | 695 | −24.221 | 43.089 | 30.285 | 1.00 | 28.72 | E | N |
| ATOM | 9955 | CA | GLU | E | 695 | −25.546 | 43.527 | 29.871 | 1.00 | 32.29 | E | C |
| ATOM | 9956 | CB | GLU | E | 695 | −26.561 | 42.383 | 30.036 | 1.00 | 38.02 | E | C |
| ATOM | 9957 | CG | GLU | E | 695 | −27.999 | 42.735 | 29.620 | 1.00 | 47.07 | E | C |
| ATOM | 9958 | CD | GLU | E | 695 | −29.057 | 42.299 | 30.646 | 1.00 | 53.40 | E | C |
| ATOM | 9959 | OE1 | GLU | E | 695 | −29.477 | 41.115 | 30.614 | 1.00 | 55.56 | E | O |
| ATOM | 9960 | OE2 | GLU | E | 695 | −29.470 | 43.143 | 31.482 | 1.00 | 55.61 | E | O |
| ATOM | 9961 | C | GLU | E | 695 | −25.990 | 44.737 | 30.684 | 1.00 | 30.46 | E | C |
| ATOM | 9962 | O | GLU | E | 695 | −26.588 | 45.670 | 30.148 | 1.00 | 30.45 | E | O |
| ATOM | 9963 | N | GLU | E | 696 | −25.692 | 44.724 | 31.976 | 1.00 | 28.52 | E | N |
| ATOM | 9964 | CA | GLU | E | 696 | −26.086 | 45.828 | 32.841 | 1.00 | 28.08 | E | C |
| ATOM | 9965 | CB | GLU | E | 696 | −25.962 | 45.416 | 34.300 | 1.00 | 30.10 | E | C |
| ATOM | 9966 | CG | GLU | E | 696 | −27.257 | 44.923 | 34.879 | 1.00 | 35.89 | E | C |
| ATOM | 9967 | CD | GLU | E | 696 | −27.044 | 44.189 | 36.180 | 1.00 | 40.50 | E | C |
| ATOM | 9968 | OE1 | GLU | E | 696 | −27.474 | 44.716 | 37.242 | 1.00 | 42.66 | E | O |
| ATOM | 9969 | OE2 | GLU | E | 696 | −26.441 | 43.090 | 36.135 | 1.00 | 41.39 | E | O |
| ATOM | 9970 | C | GLU | E | 696 | −25.261 | 47.079 | 32.590 | 1.00 | 24.93 | E | C |
| ATOM | 9971 | O | GLU | E | 696 | −25.793 | 48.188 | 32.585 | 1.00 | 21.70 | E | O |
| ATOM | 9972 | N | LYS | E | 697 | −23.960 | 46.897 | 32.386 | 1.00 | 23.57 | E | N |
| ATOM | 9973 | CA | LYS | E | 697 | −23.072 | 48.024 | 32.124 | 1.00 | 23.64 | E | C |
| ATOM | 9974 | CB | LYS | E | 697 | −21.633 | 47.544 | 31.997 | 1.00 | 21.00 | E | C |
| ATOM | 9975 | CG | LYS | E | 697 | −20.973 | 47.207 | 33.314 | 1.00 | 22.04 | E | C |
| ATOM | 9976 | CD | LYS | E | 697 | −19.462 | 47.273 | 33.185 | 1.00 | 18.49 | E | C |
| ATOM | 9977 | CE | LYS | E | 697 | −18.784 | 46.644 | 34.383 | 1.00 | 19.17 | E | C |
| ATOM | 9978 | NZ | LYS | E | 697 | −17.313 | 46.809 | 34.307 | 1.00 | 19.75 | E | N |
| ATOM | 9979 | C | LYS | E | 697 | −23.474 | 48.755 | 30.843 | 1.00 | 24.12 | E | C |
| ATOM | 9980 | O | LYS | E | 697 | −23.469 | 49.986 | 30.790 | 1.00 | 25.17 | E | O |
| ATOM | 9981 | N | ALA | E | 698 | −23.818 | 47.988 | 29.812 | 1.00 | 24.79 | E | N |
| ATOM | 9982 | CA | ALA | E | 698 | −24.223 | 48.558 | 28.530 | 1.00 | 25.10 | E | C |
| ATOM | 9983 | CB | ALA | E | 698 | −24.484 | 47.445 | 27.525 | 1.00 | 25.03 | E | C |
| ATOM | 9984 | C | ALA | E | 698 | −25.480 | 49.391 | 28.722 | 1.00 | 25.34 | E | C |
| ATOM | 9985 | O | ALA | E | 698 | −25.693 | 50.393 | 28.039 | 1.00 | 23.99 | E | O |
| ATOM | 9986 | N | LYS | E | 699 | −26.306 | 48.966 | 29.672 | 1.00 | 25.83 | E | N |
| ATOM | 9987 | CA | LYS | E | 699 | −27.552 | 49.652 | 29.982 | 1.00 | 25.78 | E | C |
| ATOM | 9988 | CB | LYS | E | 699 | −28.466 | 48.704 | 30.768 | 1.00 | 28.17 | E | C |
| ATOM | 9989 | CG | LYS | E | 699 | −29.502 | 49.366 | 31.665 | 1.00 | 31.91 | E | C |
| ATOM | 9990 | CD | LYS | E | 699 | −30.232 | 48.311 | 32.504 | 1.00 | 35.84 | E | C |
| ATOM | 9991 | CE | LYS | E | 699 | −31.021 | 48.928 | 33.652 | 1.00 | 35.83 | E | C |
| ATOM | 9992 | NZ | LYS | E | 699 | −31.873 | 50.062 | 33.199 | 1.00 | 37.81 | E | N |
| ATOM | 9993 | C | LYS | E | 699 | −27.291 | 50.936 | 30.769 | 1.00 | 24.31 | E | C |
| ATOM | 9994 | O | LYS | E | 699 | −28.058 | 51.895 | 30.674 | 1.00 | 24.22 | E | O |
| ATOM | 9995 | N | PHE | E | 700 | −26.199 | 50.955 | 31.530 | 1.00 | 23.56 | E | N |
| ATOM | 9996 | CA | PHE | E | 700 | −25.849 | 52.122 | 32.339 | 1.00 | 21.74 | E | C |
| ATOM | 9997 | CB | PHE | E | 700 | −25.051 | 51.705 | 33.585 | 1.00 | 20.20 | E | C |
| ATOM | 9998 | CG | PHE | E | 700 | −25.799 | 50.802 | 34.529 | 1.00 | 20.14 | E | C |
| ATOM | 9999 | CD1 | PHE | E | 700 | −27.191 | 50.760 | 34.535 | 1.00 | 18.00 | E | C |
| ATOM | 10000 | CD2 | PHE | E | 700 | −25.099 | 49.969 | 35.406 | 1.00 | 20.75 | E | C |
| ATOM | 10001 | CE1 | PHE | E | 700 | −27.875 | 49.901 | 35.393 | 1.00 | 16.42 | E | C |
| ATOM | 10002 | CE2 | PHE | E | 700 | −25.777 | 49.103 | 36.272 | 1.00 | 18.12 | E | C |
| ATOM | 10003 | CZ | PHE | E | 700 | −27.167 | 49.071 | 36.261 | 1.00 | 16.51 | E | C |
| ATOM | 10004 | C | PHE | E | 700 | −25.014 | 53.134 | 31.575 | 1.00 | 21.67 | E | C |
| ATOM | 10005 | O | PHE | E | 700 | −25.213 | 54.340 | 31.711 | 1.00 | 21.52 | E | O |
| ATOM | 10006 | N | LEU | E | 701 | −24.075 | 52.633 | 30.777 | 1.00 | 22.49 | E | N |
| ATOM | 10007 | CA | LEU | E | 701 | −23.152 | 53.478 | 30.021 | 1.00 | 23.48 | E | C |
| ATOM | 10008 | CB | LEU | E | 701 | −21.720 | 52.992 | 30.256 | 1.00 | 21.42 | E | C |
| ATOM | 10009 | CG | LEU | E | 701 | −21.263 | 52.788 | 31.697 | 1.00 | 19.33 | E | C |
| ATOM | 10010 | CD1 | LEU | E | 701 | −19.886 | 52.145 | 31.710 | 1.00 | 19.07 | E | C |
| ATOM | 10011 | CD2 | LEU | E | 701 | −21.233 | 54.126 | 32.408 | 1.00 | 19.06 | E | C |
| ATOM | 10012 | C | LEU | E | 701 | −23.371 | 53.584 | 28.509 | 1.00 | 24.85 | E | C |
| ATOM | 10013 | O | LEU | E | 701 | −22.840 | 54.494 | 27.865 | 1.00 | 23.65 | E | O |
| ATOM | 10014 | N | GLY | E | 702 | −24.137 | 52.657 | 27.947 | 1.00 | 25.51 | E | N |
| ATOM | 10015 | CA | GLY | E | 702 | −24.368 | 52.659 | 26.514 | 1.00 | 26.18 | E | C |
| ATOM | 10016 | C | GLY | E | 702 | −23.772 | 51.382 | 25.948 | 1.00 | 26.62 | E | C |
| ATOM | 10017 | O | GLY | E | 702 | −22.843 | 50.820 | 26.526 | 1.00 | 27.38 | E | O |
| ATOM | 10018 | N | ASN | E | 703 | −24.286 | 50.929 | 24.811 | 1.00 | 27.03 | E | N |
| ATOM | 10019 | CA | ASN | E | 703 | −23.820 | 49.688 | 24.197 | 1.00 | 27.37 | E | C |
| ATOM | 10020 | CB | ASN | E | 703 | −24.766 | 49.297 | 23.066 | 1.00 | 29.02 | E | C |
| ATOM | 10021 | CG | ASN | E | 703 | −26.182 | 49.106 | 23.547 | 1.00 | 31.26 | E | C |
| ATOM | 10022 | OD1 | ASN | E | 703 | −26.547 | 48.032 | 24.032 | 1.00 | 32.57 | E | O |
| ATOM | 10023 | ND2 | ASN | E | 703 | −26.989 | 50.153 | 23.432 | 1.00 | 33.12 | E | N |
| ATOM | 10024 | C | ASN | E | 703 | −22.389 | 49.623 | 23.690 | 1.00 | 26.25 | E | C |
| ATOM | 10025 | O | ASN | E | 703 | −21.872 | 48.537 | 23.472 | 1.00 | 26.00 | E | O |
| ATOM | 10026 | N | ASN | E | 704 | −21.741 | 50.768 | 23.514 | 1.00 | 26.89 | E | N |
| ATOM | 10027 | CA | ASN | E | 704 | −20.369 | 50.790 | 23.011 | 1.00 | 26.65 | E | C |
| ATOM | 10028 | CB | ASN | E | 704 | −20.249 | 51.833 | 21.904 | 1.00 | 31.61 | E | C |
| ATOM | 10029 | CG | ASN | E | 704 | −19.936 | 51.221 | 20.564 | 1.00 | 35.16 | E | C |
| ATOM | 10030 | OD1 | ASN | E | 704 | −18.771 | 50.990 | 20.230 | 1.00 | 36.94 | E | O |
| ATOM | 10031 | ND2 | ASN | E | 704 | −20.977 | 50.953 | 19.782 | 1.00 | 37.88 | E | N |
| ATOM | 10032 | C | ASN | E | 704 | −19.335 | 51.102 | 24.079 | 1.00 | 24.28 | E | C |
| ATOM | 10033 | O | ASN | E | 704 | −18.175 | 51.373 | 23.767 | 1.00 | 23.10 | E | O |
| ATOM | 10034 | N | TYR | E | 705 | −19.755 | 51.051 | 25.338 | 1.00 | 24.11 | E | N |
| ATOM | 10035 | CA | TYR | E | 705 | −18.884 | 51.371 | 26.467 | 1.00 | 20.68 | E | C |
| ATOM | 10036 | CB | TYR | E | 705 | −19.642 | 51.110 | 27.778 | 1.00 | 18.86 | E | C |
| ATOM | 10037 | CG | TYR | E | 705 | −19.598 | 49.680 | 28.258 | 1.00 | 17.21 | E | C |
| ATOM | 10038 | CD1 | TYR | E | 705 | −20.591 | 48.773 | 27.899 | 1.00 | 16.41 | E | C |
| ATOM | 10039 | CE1 | TYR | E | 705 | −20.543 | 47.450 | 28.332 | 1.00 | 16.48 | E | C |
| ATOM | 10040 | CD2 | TYR | E | 705 | −18.551 | 49.230 | 29.069 | 1.00 | 17.71 | E | C |
| ATOM | 10041 | CE2 | TYR | E | 705 | −18.492 | 47.913 | 29.510 | 1.00 | 15.85 | E | C |
| ATOM | 10042 | CZ | TYR | E | 705 | −19.490 | 47.030 | 29.137 | 1.00 | 18.17 | E | C |
| ATOM | 10043 | OH | TYR | E | 705 | −19.431 | 45.728 | 29.568 | 1.00 | 20.62 | E | O |
| ATOM | 10044 | C | TYR | E | 705 | −17.504 | 50.698 | 26.486 | 1.00 | 19.72 | E | C |
| ATOM | 10045 | O | TYR | E | 705 | −16.559 | 51.235 | 27.067 | 1.00 | 19.39 | E | O |
| ATOM | 10046 | N | LEU | E | 706 | −17.370 | 49.544 | 25.844 | 1.00 | 19.33 | E | N |
| ATOM | 10047 | CA | LEU | E | 706 | −16.087 | 48.851 | 25.828 | 1.00 | 21.84 | E | C |
| ATOM | 10048 | CB | LEU | E | 706 | −16.277 | 47.376 | 25.457 | 1.00 | 21.77 | E | C |
| ATOM | 10049 | CG | LEU | E | 706 | −16.762 | 46.429 | 26.565 | 1.00 | 23.58 | E | C |
| ATOM | 10050 | CD1 | LEU | E | 706 | −17.235 | 45.114 | 25.954 | 1.00 | 21.15 | E | C |
| ATOM | 10051 | CD2 | LEU | E | 706 | −15.642 | 46.175 | 27.559 | 1.00 | 20.95 | E | C |
| ATOM | 10052 | C | LEU | E | 706 | −15.093 | 49.503 | 24.866 | 1.00 | 23.57 | E | C |
| ATOM | 10053 | O | LEU | E | 706 | −13.896 | 49.220 | 24.914 | 1.00 | 23.98 | E | O |
| ATOM | 10054 | N | GLU | E | 707 | −15.589 | 50.379 | 23.997 | 1.00 | 25.24 | E | N |
| ATOM | 10055 | CA | GLU | E | 707 | −14.739 | 51.070 | 23.032 | 1.00 | 26.06 | E | C |
| ATOM | 10056 | CB | GLU | E | 707 | −15.573 | 51.508 | 21.826 | 1.00 | 29.77 | E | C |
| ATOM | 10057 | CG | GLU | E | 707 | −16.040 | 50.358 | 20.954 | 1.00 | 35.27 | E | C |
| ATOM | 10058 | CD | GLU | E | 707 | −14.888 | 49.484 | 20.499 | 1.00 | 39.32 | E | C |
| ATOM | 10059 | OE1 | GLU | E | 707 | −14.926 | 48.258 | 20.749 | 1.00 | 42.14 | E | O |
| ATOM | 10060 | OE2 | GLU | E | 707 | −13.938 | 50.029 | 19.895 | 1.00 | 40.99 | E | O |
| ATOM | 10061 | C | GLU | E | 707 | −14.090 | 52.294 | 23.675 | 1.00 | 25.22 | E | C |
| ATOM | 10062 | O | GLU | E | 707 | −14.767 | 53.091 | 24.318 | 1.00 | 25.56 | E | O |
| ATOM | 10063 | N | GLU | E | 708 | −12.784 | 52.447 | 23.485 | 1.00 | 24.92 | E | N |
| ATOM | 10064 | CA | GLU | E | 708 | −12.041 | 53.570 | 24.056 | 1.00 | 24.71 | E | C |
| ATOM | 10065 | CB | GLU | E | 708 | −10.552 | 53.215 | 24.149 | 1.00 | 26.75 | E | C |
| ATOM | 10066 | CG | GLU | E | 708 | −10.280 | 51.716 | 24.092 | 1.00 | 31.30 | E | C |
| ATOM | 10067 | CD | GLU | E | 708 | −9.197 | 51.262 | 25.049 | 1.00 | 31.81 | E | C |
| ATOM | 10068 | OE1 | GLU | E | 708 | −8.139 | 51.915 | 25.103 | 1.00 | 34.12 | E | O |
| ATOM | 10069 | OE2 | GLU | E | 708 | −9.398 | 50.244 | 25.746 | 1.00 | 33.47 | E | O |
| ATOM | 10070 | C | GLU | E | 708 | −12.213 | 54.886 | 23.290 | 1.00 | 23.33 | E | C |
| ATOM | 10071 | O | GLU | E | 708 | −12.401 | 54.893 | 22.072 | 1.00 | 23.54 | E | O |
| ATOM | 10072 | N | GLY | E | 709 | −12.156 | 55.999 | 24.020 | 1.00 | 20.50 | E | N |
| ATOM | 10073 | CA | GLY | E | 709 | −12.302 | 57.304 | 23.405 | 1.00 | 17.45 | E | C |
| ATOM | 10074 | C | GLY | E | 709 | −13.746 | 57.748 | 23.308 | 1.00 | 17.30 | E | C |
| ATOM | 10075 | O | GLY | E | 709 | −14.642 | 57.052 | 23.792 | 1.00 | 16.72 | E | O |
| ATOM | 10076 | N | PRO | E | 710 | −14.009 | 58.908 | 22.685 | 1.00 | 16.20 | E | N |
| ATOM | 10077 | CD | PRO | E | 710 | −12.995 | 59.801 | 22.095 | 1.00 | 14.60 | E | C |
| ATOM | 10078 | CA | PRO | E | 710 | −15.364 | 59.444 | 22.532 | 1.00 | 15.93 | E | C |
| ATOM | 10079 | CB | PRO | E | 710 | −15.166 | 60.668 | 21.643 | 1.00 | 15.49 | E | C |
| ATOM | 10080 | CG | PRO | E | 710 | −13.752 | 61.073 | 21.877 | 1.00 | 14.32 | E | C |
| ATOM | 10081 | C | PRO | E | 710 | −16.387 | 58.480 | 21.939 | 1.00 | 17.42 | E | C |
| ATOM | 10082 | O | PRO | E | 710 | −17.576 | 58.571 | 22.231 | 1.00 | 18.48 | E | O |
| ATOM | 10083 | N | ILE | E | 711 | −15.927 | 57.562 | 21.102 | 1.00 | 17.30 | E | N |
| ATOM | 10084 | CA | ILE | E | 711 | −16.818 | 56.616 | 20.452 | 1.00 | 18.33 | E | C |
| ATOM | 10085 | CB | ILE | E | 711 | −16.047 | 55.776 | 19.400 | 1.00 | 19.16 | E | C |
| ATOM | 10086 | CG2 | ILE | E | 711 | −15.323 | 54.616 | 20.067 | 1.00 | 19.13 | E | C |
| ATOM | 10087 | CG1 | ILE | E | 711 | −17.017 | 55.262 | 18.338 | 1.00 | 20.78 | E | C |
| ATOM | 10088 | CD1 | ILE | E | 711 | −17.844 | 56.353 | 17.675 | 1.00 | 19.42 | E | C |
| ATOM | 10089 | C | ILE | E | 711 | −17.518 | 55.693 | 21.442 | 1.00 | 19.43 | E | C |
| ATOM | 10090 | O | ILE | E | 711 | −18.638 | 55.234 | 21.197 | 1.00 | 20.06 | E | O |
| ATOM | 10091 | N | GLY | E | 712 | −16.866 | 55.432 | 22.569 | 1.00 | 18.86 | E | N |
| ATOM | 10092 | CA | GLY | E | 712 | −17.459 | 54.564 | 23.566 | 1.00 | 19.06 | E | C |
| ATOM | 10093 | C | GLY | E | 712 | −18.354 | 55.258 | 24.580 | 1.00 | 18.84 | E | C |
| ATOM | 10094 | O | GLY | E | 712 | −18.938 | 54.596 | 25.430 | 1.00 | 20.49 | E | O |
| ATOM | 10095 | N | ASN | E | 713 | −18.484 | 56.577 | 24.494 | 1.00 | 18.01 | E | N |
| ATOM | 10096 | CA | ASN | E | 713 | −19.305 | 57.314 | 25.452 | 1.00 | 17.06 | E | C |
| ATOM | 10097 | CB | ASN | E | 713 | −18.545 | 58.541 | 25.987 | 1.00 | 14.95 | E | C |
| ATOM | 10098 | CG | ASN | E | 713 | −19.361 | 59.347 | 26.988 | 1.00 | 14.54 | E | C |
| ATOM | 10099 | OD1 | ASN | E | 713 | −19.520 | 60.559 | 26.848 | 1.00 | 17.26 | E | O |
| ATOM | 10100 | ND2 | ASN | E | 713 | −19.883 | 58.674 | 28.007 | 1.00 | 12.38 | E | N |
| ATOM | 10101 | C | ASN | E | 713 | −20.646 | 57.770 | 24.909 | 1.00 | 18.95 | E | C |
| ATOM | 10102 | O | ASN | E | 713 | −20.718 | 58.397 | 23.853 | 1.00 | 18.03 | E | O |
| ATOM | 10103 | N | ASP | E | 714 | −21.703 | 57.453 | 25.656 | 1.00 | 19.37 | E | N |
| ATOM | 10104 | CA | ASP | E | 714 | −23.064 | 57.849 | 25.311 | 1.00 | 19.14 | E | C |
| ATOM | 10105 | CB | ASP | E | 714 | −23.991 | 56.630 | 25.319 | 1.00 | 19.64 | E | C |
| ATOM | 10106 | CG | ASP | E | 714 | −25.396 | 56.955 | 24.827 | 1.00 | 21.23 | E | C |
| ATOM | 10107 | OD1 | ASP | E | 714 | −25.747 | 58.154 | 24.721 | 1.00 | 22.35 | E | O |
| ATOM | 10108 | OD2 | ASP | E | 714 | −26.153 | 56.002 | 24.546 | 1.00 | 20.62 | E | O |
| ATOM | 10109 | C | ASP | E | 714 | −23.487 | 58.838 | 26.395 | 1.00 | 18.76 | E | C |
| ATOM | 10110 | O | ASP | E | 714 | −23.975 | 58.437 | 27.447 | 1.00 | 18.65 | E | O |
| ATOM | 10111 | N | ILE | E | 715 | −23.284 | 60.125 | 26.130 | 1.00 | 18.63 | E | N |
| ATOM | 10112 | CA | ILE | E | 715 | −23.605 | 61.180 | 27.078 | 1.00 | 18.80 | E | C |
| ATOM | 10113 | CB | ILE | E | 715 | −23.318 | 62.577 | 26.473 | 1.00 | 19.41 | E | C |
| ATOM | 10114 | CG2 | ILE | E | 715 | −24.392 | 62.939 | 25.465 | 1.00 | 19.88 | E | C |
| ATOM | 10115 | CG1 | ILE | E | 715 | −23.253 | 63.631 | 27.581 | 1.00 | 16.82 | E | C |
| ATOM | 10116 | CD1 | ILE | E | 715 | −22.996 | 65.032 | 27.071 | 1.00 | 14.84 | E | C |
| ATOM | 10117 | C | ILE | E | 715 | −25.037 | 61.133 | 27.563 | 1.00 | 19.42 | E | C |
| ATOM | 10118 | O | ILE | E | 715 | −25.342 | 61.608 | 28.660 | 1.00 | 20.10 | E | O |
| ATOM | 10119 | N | ARG | E | 716 | −25.922 | 60.558 | 26.758 | 1.00 | 20.24 | E | N |
| ATOM | 10120 | CA | ARG | E | 716 | −27.324 | 60.464 | 27.147 | 1.00 | 22.43 | E | C |
| ATOM | 10121 | CB | ARG | E | 716 | −28.159 | 59.886 | 26.000 | 1.00 | 25.83 | E | C |
| ATOM | 10122 | CG | ARG | E | 716 | −28.585 | 60.911 | 24.956 | 1.00 | 30.76 | E | C |
| ATOM | 10123 | CD | ARG | E | 716 | −29.298 | 60.251 | 23.783 | 1.00 | 36.88 | E | C |
| ATOM | 10124 | NE | ARG | E | 716 | −28.608 | 59.043 | 23.325 | 1.00 | 42.98 | E | N |
| ATOM | 10125 | CZ | ARG | E | 716 | −29.132 | 58.147 | 22.488 | 1.00 | 44.28 | E | C |
| ATOM | 10126 | NH1 | ARG | E | 716 | −30.359 | 58.318 | 22.010 | 1.00 | 45.81 | E | N |
| ATOM | 10127 | NH2 | ARG | E | 716 | −28.429 | 57.079 | 22.125 | 1.00 | 44.44 | E | N |
| ATOM | 10128 | C | ARG | E | 716 | −27.456 | 59.575 | 28.378 | 1.00 | 21.63 | E | C |
| ATOM | 10129 | O | ARG | E | 716 | −28.420 | 59.675 | 29.133 | 1.00 | 22.46 | E | O |
| ATOM | 10130 | N | LYS | E | 717 | −26.469 | 58.710 | 28.576 | 1.00 | 21.04 | E | N |
| ATOM | 10131 | CA | LYS | E | 717 | −26.462 | 57.785 | 29.699 | 1.00 | 21.76 | E | C |
| ATOM | 10132 | CB | LYS | E | 717 | −26.138 | 56.377 | 29.195 | 1.00 | 21.88 | E | C |
| ATOM | 10133 | CG | LYS | E | 717 | −27.364 | 55.512 | 28.978 | 1.00 | 25.16 | E | C |
| ATOM | 10134 | CD | LYS | E | 717 | −27.175 | 54.581 | 27.807 | 1.00 | 26.77 | E | C |
| ATOM | 10135 | CE | LYS | E | 717 | −28.406 | 53.707 | 27.601 | 1.00 | 29.61 | E | C |
| ATOM | 10136 | NZ | LYS | E | 717 | −28.042 | 52.348 | 27.079 | 1.00 | 33.13 | E | N |
| ATOM | 10137 | C | LYS | E | 717 | −25.485 | 58.148 | 30.821 | 1.00 | 21.04 | E | C |
| ATOM | 10138 | O | LYS | E | 717 | −25.755 | 57.888 | 31.995 | 1.00 | 21.24 | E | O |
| ATOM | 10139 | N | THR | E | 718 | −24.362 | 58.758 | 30.459 | 1.00 | 19.10 | E | N |
| ATOM | 10140 | CA | THR | E | 718 | −23.330 | 59.105 | 31.426 | 1.00 | 17.66 | E | C |
| ATOM | 10141 | CB | THR | E | 718 | −21.951 | 58.698 | 30.894 | 1.00 | 17.57 | E | C |
| ATOM | 10142 | OG1 | THR | E | 718 | −21.581 | 59.582 | 29.826 | 1.00 | 19.47 | E | O |
| ATOM | 10143 | CG2 | THR | E | 718 | −21.977 | 57.265 | 30.376 | 1.00 | 15.85 | E | C |
| ATOM | 10144 | C | THR | E | 718 | −23.230 | 60.568 | 31.849 | 1.00 | 18.12 | E | C |
| ATOM | 10145 | O | THR | E | 718 | −22.637 | 60.868 | 32.883 | 1.00 | 17.85 | E | O |
| ATOM | 10146 | N | ASN | E | 719 | −23.789 | 61.479 | 31.061 | 1.00 | 16.78 | E | N |
| ATOM | 10147 | CA | ASN | E | 719 | −23.702 | 62.907 | 31.366 | 1.00 | 15.86 | E | C |
| ATOM | 10148 | CB | ASN | E | 719 | −24.418 | 63.241 | 32.679 | 1.00 | 17.59 | E | C |
| ATOM | 10149 | CG | ASN | E | 719 | −24.836 | 64.712 | 32.758 | 1.00 | 20.35 | E | C |
| ATOM | 10150 | OD1 | ASN | E | 719 | −25.541 | 65.224 | 31.886 | 1.00 | 20.74 | E | O |
| ATOM | 10151 | ND2 | ASN | E | 719 | −24.400 | 65.391 | 33.808 | 1.00 | 21.17 | E | N |
| ATOM | 10152 | C | ASN | E | 719 | −22.245 | 63.386 | 31.429 | 1.00 | 14.94 | E | C |
| ATOM | 10153 | O | ASN | E | 719 | −21.914 | 64.334 | 32.147 | 1.00 | 13.94 | E | O |
| ATOM | 10154 | N | VAL | E | 720 | −21.377 | 62.708 | 30.683 | 1.00 | 14.23 | E | N |
| ATOM | 10155 | CA | VAL | E | 720 | −19.969 | 63.075 | 30.596 | 1.00 | 14.62 | E | C |
| ATOM | 10156 | CB | VAL | E | 720 | −19.039 | 61.835 | 30.661 | 1.00 | 15.85 | E | C |
| ATOM | 10157 | CG1 | VAL | E | 720 | −17.616 | 62.232 | 30.264 | 1.00 | 15.65 | E | C |
| ATOM | 10158 | CG2 | VAL | E | 720 | −19.045 | 61.234 | 32.072 | 1.00 | 14.16 | E | C |
| ATOM | 10159 | C | VAL | E | 720 | −19.800 | 63.745 | 29.223 | 1.00 | 15.52 | E | C |
| ATOM | 10160 | O | VAL | E | 720 | −20.210 | 63.188 | 28.200 | 1.00 | 15.02 | E | O |
| ATOM | 10161 | N | ALA | E | 721 | −19.196 | 64.931 | 29.207 | 1.00 | 15.06 | E | N |
| ATOM | 10162 | CA | ALA | E | 721 | −18.991 | 65.689 | 27.972 | 1.00 | 13.31 | E | C |
| ATOM | 10163 | CB | ALA | E | 721 | −18.431 | 67.059 | 28.304 | 1.00 | 11.04 | E | C |
| ATOM | 10164 | C | ALA | E | 721 | −18.074 | 64.991 | 26.973 | 1.00 | 13.41 | E | C |
| ATOM | 10165 | O | ALA | E | 721 | −17.086 | 64.371 | 27.349 | 1.00 | 12.05 | E | O |
| ATOM | 10166 | N | GLN | E | 722 | −18.397 | 65.107 | 25.690 | 1.00 | 14.05 | E | N |
| ATOM | 10167 | CA | GLN | E | 722 | −17.574 | 64.493 | 24.657 | 1.00 | 13.17 | E | C |
| ATOM | 10168 | CB | GLN | E | 722 | −18.320 | 64.487 | 23.320 | 1.00 | 15.89 | E | C |
| ATOM | 10169 | CG | GLN | E | 722 | −19.359 | 63.367 | 23.199 | 1.00 | 15.88 | E | C |
| ATOM | 10170 | CD | GLN | E | 722 | −18.746 | 61.972 | 23.272 | 1.00 | 17.97 | E | C |
| ATOM | 10171 | OE1 | GLN | E | 722 | −18.867 | 61.173 | 22.341 | 1.00 | 20.79 | E | O |
| ATOM | 10172 | NE2 | GLN | E | 722 | −18.089 | 61.675 | 24.378 | 1.00 | 18.26 | E | N |
| ATOM | 10173 | C | GLN | E | 722 | −16.262 | 65.264 | 24.546 | 1.00 | 12.99 | E | C |
| ATOM | 10174 | O | GLN | E | 722 | −15.244 | 64.732 | 24.096 | 1.00 | 13.38 | E | O |
| ATOM | 10175 | N | ILE | E | 723 | −16.289 | 66.525 | 24.967 | 1.00 | 13.18 | E | N |
| ATOM | 10176 | CA | ILE | E | 723 | −15.093 | 67.361 | 24.961 | 1.00 | 13.52 | E | C |
| ATOM | 10177 | CB | ILE | E | 723 | −15.425 | 68.793 | 25.444 | 1.00 | 14.20 | E | C |
| ATOM | 10178 | CG2 | ILE | E | 723 | −14.147 | 69.532 | 25.842 | 1.00 | 13.96 | E | C |
| ATOM | 10179 | CG1 | ILE | E | 723 | −16.153 | 69.551 | 24.333 | 1.00 | 14.79 | E | C |
| ATOM | 10180 | CD1 | ILE | E | 723 | −16.614 | 70.945 | 24.722 | 1.00 | 12.34 | E | C |
| ATOM | 10181 | C | ILE | E | 723 | −14.080 | 66.724 | 25.922 | 1.00 | 14.48 | E | C |
| ATOM | 10182 | O | ILE | E | 723 | −12.879 | 66.645 | 25.631 | 1.00 | 15.76 | E | O |
| ATOM | 10183 | N | ARG | E | 724 | −14.586 | 66.262 | 27.065 | 1.00 | 14.26 | E | N |
| ATOM | 10184 | CA | ARG | E | 724 | −13.763 | 65.619 | 28.084 | 1.00 | 12.58 | E | C |
| ATOM | 10185 | CB | ARG | E | 724 | −14.603 | 65.389 | 29.356 | 1.00 | 14.62 | E | C |
| ATOM | 10186 | CG | ARG | E | 724 | −13.862 | 64.722 | 30.534 | 1.00 | 14.00 | E | C |
| ATOM | 10187 | CD | ARG | E | 724 | −12.607 | 65.496 | 30.947 | 1.00 | 13.66 | E | C |
| ATOM | 10188 | NE | ARG | E | 724 | −12.923 | 66.820 | 31.474 | 1.00 | 13.33 | E | N |
| ATOM | 10189 | CZ | ARG | E | 724 | −13.202 | 67.076 | 32.751 | 1.00 | 15.53 | E | C |
| ATOM | 10190 | NH1 | ARG | E | 724 | −13.207 | 66.098 | 33.647 | 1.00 | 14.51 | E | N |
| ATOM | 10191 | NH2 | ARG | E | 724 | −13.491 | 68.311 | 33.134 | 1.00 | 13.40 | E | N |
| ATOM | 10192 | C | ARG | E | 724 | −13.235 | 64.294 | 27.541 | 1.00 | 10.92 | E | C |
| ATOM | 10193 | O | ARG | E | 724 | −12.047 | 63.995 | 27.645 | 1.00 | 10.11 | E | O |
| ATOM | 10194 | N | MET | E | 725 | −14.124 | 63.502 | 26.952 | 1.00 | 10.63 | E | N |
| ATOM | 10195 | CA | MET | E | 725 | −13.725 | 62.215 | 26.393 | 1.00 | 12.60 | E | C |
| ATOM | 10196 | CB | MET | E | 725 | −14.931 | 61.527 | 25.749 | 1.00 | 10.49 | E | C |
| ATOM | 10197 | CG | MET | E | 725 | −15.988 | 61.072 | 26.737 | 1.00 | 9.19 | E | C |
| ATOM | 10198 | SD | MET | E | 725 | −15.385 | 59.809 | 27.897 | 1.00 | 12.92 | E | S |
| ATOM | 10199 | CE | MET | E | 725 | −14.825 | 58.516 | 26.807 | 1.00 | 7.80 | E | C |
| ATOM | 10200 | C | MET | E | 725 | −12.606 | 62.379 | 25.357 | 1.00 | 12.98 | E | C |
| ATOM | 10201 | O | MET | E | 725 | −11.614 | 61.653 | 25.383 | 1.00 | 15.67 | E | O |
| ATOM | 10202 | N | ALA | E | 726 | −12.773 | 63.343 | 24.454 | 1.00 | 14.49 | E | N |
| ATOM | 10203 | CA | ALA | E | 726 | −11.790 | 63.603 | 23.409 | 1.00 | 14.99 | E | C |
| ATOM | 10204 | CB | ALA | E | 726 | −12.335 | 64.640 | 22.412 | 1.00 | 12.89 | E | C |
| ATOM | 10205 | C | ALA | E | 726 | −10.476 | 64.089 | 24.010 | 1.00 | 14.90 | E | C |
| ATOM | 10206 | O | ALA | E | 726 | −9.395 | 63.672 | 23.583 | 1.00 | 13.81 | E | O |
| ATOM | 10207 | N | TYR | E | 727 | −10.569 | 64.977 | 24.997 | 1.00 | 14.14 | E | N |
| ATOM | 10208 | CA | TYR | E | 727 | −9.370 | 65.501 | 25.641 | 1.00 | 12.53 | E | C |
| ATOM | 10209 | CB | TYR | E | 727 | −9.738 | 66.493 | 26.755 | 1.00 | 12.00 | E | C |
| ATOM | 10210 | CG | TYR | E | 727 | −8.539 | 66.889 | 27.590 | 1.00 | 11.32 | E | C |
| ATOM | 10211 | CD1 | TYR | E | 727 | −8.228 | 66.212 | 28.768 | 1.00 | 11.16 | E | C |
| ATOM | 10212 | CE1 | TYR | E | 727 | −7.079 | 66.526 | 29.500 | 1.00 | 10.75 | E | C |
| ATOM | 10213 | CD2 | TYR | E | 727 | −7.674 | 67.894 | 27.165 | 1.00 | 9.40 | E | C |
| ATOM | 10214 | CE2 | TYR | E | 727 | −6.519 | 68.217 | 27.890 | 1.00 | 7.90 | E | C |
| ATOM | 10215 | CZ | TYR | E | 727 | −6.231 | 67.529 | 29.053 | 1.00 | 10.29 | E | C |
| ATOM | 10216 | OH | TYR | E | 727 | −5.110 | 67.850 | 29.786 | 1.00 | 11.98 | E | O |
| ATOM | 10217 | C | TYR | E | 727 | −8.517 | 64.374 | 26.228 | 1.00 | 12.18 | E | C |
| ATOM | 10218 | O | TYR | E | 727 | −7.323 | 64.300 | 25.966 | 1.00 | 11.40 | E | O |
| ATOM | 10219 | N | ARG | E | 728 | −9.131 | 63.500 | 27.023 | 1.00 | 12.42 | E | N |
| ATOM | 10220 | CA | ARG | E | 728 | −8.408 | 62.391 | 27.644 | 1.00 | 11.05 | E | C |
| ATOM | 10221 | CB | ARG | E | 728 | −9.342 | 61.557 | 28.538 | 1.00 | 11.17 | E | C |
| ATOM | 10222 | CG | ARG | E | 728 | −10.000 | 62.325 | 29.676 | 1.00 | 12.91 | E | C |
| ATOM | 10223 | CD | ARG | E | 728 | −9.007 | 62.704 | 30.757 | 1.00 | 11.74 | E | C |
| ATOM | 10224 | NE | ARG | E | 728 | −9.691 | 63.249 | 31.930 | 1.00 | 13.03 | E | N |
| ATOM | 10225 | CZ | ARG | E | 728 | −9.076 | 63.846 | 32.943 | 1.00 | 10.13 | E | C |
| ATOM | 10226 | NH1 | ARG | E | 728 | −7.759 | 63.979 | 32.934 | 1.00 | 8.39 | E | N |
| ATOM | 10227 | NH2 | ARG | E | 728 | −9.782 | 64.316 | 33.962 | 1.00 | 10.72 | E | N |
| ATOM | 10228 | C | ARG | E | 728 | −7.794 | 61.463 | 26.613 | 1.00 | 12.88 | E | C |
| ATOM | 10229 | O | ARG | E | 728 | −6.625 | 61.085 | 26.704 | 1.00 | 12.53 | E | O |
| ATOM | 10230 | N | TYR | E | 729 | −8.606 | 61.074 | 25.639 | 1.00 | 14.20 | E | N |
| ATOM | 10231 | CA | TYR | E | 729 | −8.156 | 60.165 | 24.601 | 1.00 | 13.30 | E | C |
| ATOM | 10232 | CB | TYR | E | 729 | −9.291 | 59.932 | 23.611 | 1.00 | 16.58 | E | C |
| ATOM | 10233 | CG | TYR | E | 729 | −9.024 | 58.807 | 22.654 | 1.00 | 21.77 | E | C |
| ATOM | 10234 | CD1 | TYR | E | 729 | −8.522 | 57.587 | 23.103 | 1.00 | 20.72 | E | C |
| ATOM | 10235 | CE1 | TYR | E | 729 | −8.256 | 56.552 | 22.212 | 1.00 | 23.41 | E | C |
| ATOM | 10236 | CD2 | TYR | E | 729 | −9.258 | 58.967 | 21.285 | 1.00 | 23.78 | E | C |
| ATOM | 10237 | CE2 | TYR | E | 729 | −8.996 | 57.941 | 20.387 | 1.00 | 24.15 | E | C |
| ATOM | 10238 | CZ | TYR | E | 729 | −8.495 | 56.738 | 20.856 | 1.00 | 25.46 | E | C |
| ATOM | 10239 | OH | TYR | E | 729 | −8.231 | 55.733 | 19.958 | 1.00 | 28.02 | E | O |
| ATOM | 10240 | C | TYR | E | 729 | −6.931 | 60.703 | 23.885 | 1.00 | 11.82 | E | C |
| ATOM | 10241 | O | TYR | E | 729 | −5.926 | 60.012 | 23.745 | 1.00 | 12.36 | E | O |
| ATOM | 10242 | N | GLU | E | 730 | −7.013 | 61.952 | 23.449 | 1.00 | 13.50 | E | N |
| ATOM | 10243 | CA | GLU | E | 730 | −5.910 | 62.582 | 22.736 | 1.00 | 13.72 | E | C |
| ATOM | 10244 | CB | GLU | E | 730 | −6.336 | 63.961 | 22.220 | 1.00 | 12.65 | E | C |
| ATOM | 10245 | CG | GLU | E | 730 | −7.525 | 63.920 | 21.279 | 1.00 | 13.99 | E | C |
| ATOM | 10246 | CD | GLU | E | 730 | −8.065 | 65.295 | 20.963 | 1.00 | 16.75 | E | C |
| ATOM | 10247 | OE1 | GLU | E | 730 | −9.124 | 65.380 | 20.308 | 1.00 | 19.61 | E | O |
| ATOM | 10248 | OE2 | GLU | E | 730 | −7.432 | 66.292 | 21.369 | 1.00 | 19.73 | E | O |
| ATOM | 10249 | C | GLU | E | 730 | −4.642 | 62.712 | 23.568 | 1.00 | 13.94 | E | C |
| ATOM | 10250 | O | GLU | E | 730 | −3.550 | 62.414 | 23.077 | 1.00 | 16.03 | E | O |
| ATOM | 10251 | N | THR | E | 731 | −4.753 | 63.148 | 24.821 | 1.00 | 13.35 | E | N |
| ATOM | 10252 | CA | THR | E | 731 | −3.532 | 63.288 | 25.610 | 1.00 | 13.52 | E | C |
| ATOM | 10253 | CB | THR | E | 731 | −3.738 | 64.224 | 26.849 | 1.00 | 14.74 | E | C |
| ATOM | 10254 | OG1 | THR | E | 731 | −3.719 | 63.459 | 28.055 | 1.00 | 19.70 | E | O |
| ATOM | 10255 | CG2 | THR | E | 731 | −5.020 | 64.984 | 26.743 | 1.00 | 7.99 | E | C |
| ATOM | 10256 | C | THR | E | 731 | −2.941 | 61.927 | 26.008 | 1.00 | 13.11 | E | C |
| ATOM | 10257 | O | THR | E | 731 | −1.724 | 61.792 | 26.162 | 1.00 | 13.83 | E | O |
| ATOM | 10258 | N | TRP | E | 732 | −3.792 | 60.912 | 26.140 | 1.00 | 11.93 | E | N |
| ATOM | 10259 | CA | TRP | E | 732 | −3.319 | 59.569 | 26.477 | 1.00 | 11.20 | E | C |
| ATOM | 10260 | CB | TRP | E | 732 | −4.503 | 58.661 | 26.809 | 1.00 | 8.10 | E | C |
| ATOM | 10261 | CG | TRP | E | 732 | −4.146 | 57.233 | 27.133 | 1.00 | 7.14 | E | C |
| ATOM | 10262 | CD2 | TRP | E | 732 | −5.007 | 56.088 | 27.007 | 1.00 | 6.83 | E | C |
| ATOM | 10263 | CE2 | TRP | E | 732 | −4.289 | 54.966 | 27.479 | 1.00 | 5.70 | E | C |
| ATOM | 10264 | CE3 | TRP | E | 732 | −6.320 | 55.905 | 26.542 | 1.00 | 8.74 | E | C |
| ATOM | 10265 | CD1 | TRP | E | 732 | −2.969 | 56.768 | 27.659 | 1.00 | 7.68 | E | C |
| ATOM | 10266 | NE1 | TRP | E | 732 | −3.050 | 55.406 | 27.870 | 1.00 | 6.08 | E | N |
| ATOM | 10267 | CZ2 | TRP | E | 732 | −4.839 | 53.676 | 27.501 | 1.00 | 5.60 | E | C |
| ATOM | 10268 | CZ3 | TRP | E | 732 | −6.867 | 54.615 | 26.566 | 1.00 | 10.27 | E | C |
| ATOM | 10269 | CH2 | TRP | E | 732 | −6.121 | 53.520 | 27.045 | 1.00 | 5.59 | E | C |
| ATOM | 10270 | C | TRP | E | 732 | −2.561 | 59.021 | 25.269 | 1.00 | 13.47 | E | C |
| ATOM | 10271 | O | TRP | E | 732 | −1.465 | 58.473 | 25.401 | 1.00 | 16.17 | E | O |
| ATOM | 10272 | N | CYS | E | 733 | −3.150 | 59.178 | 24.085 | 1.00 | 15.41 | E | N |
| ATOM | 10273 | CA | CYS | E | 733 | −2.516 | 58.710 | 22.849 | 1.00 | 16.42 | E | C |
| ATOM | 10274 | CB | CYS | E | 733 | −3.426 | 58.984 | 21.646 | 1.00 | 16.06 | E | C |
| ATOM | 10275 | SG | CYS | E | 733 | −4.725 | 57.747 | 21.406 | 1.00 | 23.03 | E | S |
| ATOM | 10276 | C | CYS | E | 733 | −1.176 | 59.415 | 22.643 | 1.00 | 15.15 | E | C |
| ATOM | 10277 | O | CYS | E | 733 | −0.175 | 58.795 | 22.276 | 1.00 | 15.47 | E | O |
| ATOM | 10278 | N | TYR | E | 734 | −1.161 | 60.716 | 22.893 | 1.00 | 15.08 | E | N |
| ATOM | 10279 | CA | TYR | E | 734 | 0.046 | 61.507 | 22.731 | 1.00 | 15.02 | E | C |
| ATOM | 10280 | CB | TYR | E | 734 | −0.254 | 62.960 | 23.080 | 1.00 | 15.68 | E | C |
| ATOM | 10281 | CG | TYR | E | 734 | 0.850 | 63.918 | 22.706 | 1.00 | 20.22 | E | C |
| ATOM | 10282 | CD1 | TYR | E | 734 | 0.817 | 64.621 | 21.501 | 1.00 | 21.66 | E | C |
| ATOM | 10283 | CE1 | TYR | E | 734 | 1.820 | 65.528 | 21.168 | 1.00 | 22.90 | E | C |
| ATOM | 10284 | CD2 | TYR | E | 734 | 1.918 | 64.143 | 23.568 | 1.00 | 22.29 | E | C |
| ATOM | 10285 | CE2 | TYR | E | 734 | 2.928 | 65.047 | 23.247 | 1.00 | 24.35 | E | C |
| ATOM | 10286 | CZ | TYR | E | 734 | 2.873 | 65.739 | 22.049 | 1.00 | 24.90 | E | C |
| ATOM | 10287 | OH | TYR | E | 734 | 3.857 | 66.661 | 21.758 | 1.00 | 26.50 | E | O |
| ATOM | 10288 | C | TYR | E | 734 | 1.217 | 60.997 | 23.575 | 1.00 | 16.09 | E | C |
| ATOM | 10289 | O | TYR | E | 734 | 2.357 | 60.955 | 23.112 | 1.00 | 15.65 | E | O |
| ATOM | 10290 | N | GLU | E | 735 | 0.942 | 60.607 | 24.817 | 1.00 | 17.17 | E | N |
| ATOM | 10291 | CA | GLU | E | 735 | 1.997 | 60.114 | 25.693 | 1.00 | 15.28 | E | C |
| ATOM | 10292 | CB | GLU | E | 735 | 1.475 | 60.001 | 27.130 | 1.00 | 17.44 | E | C |
| ATOM | 10293 | CG | GLU | E | 735 | 1.124 | 61.347 | 27.768 | 1.00 | 15.96 | E | C |
| ATOM | 10294 | CD | GLU | E | 735 | 2.313 | 62.307 | 27.840 | 1.00 | 15.23 | E | C |
| ATOM | 10295 | OE1 | GLU | E | 735 | 3.398 | 61.901 | 28.308 | 1.00 | 16.12 | E | O |
| ATOM | 10296 | OE2 | GLU | E | 735 | 2.159 | 63.475 | 27.430 | 1.00 | 16.88 | E | O |
| ATOM | 10297 | C | GLU | E | 735 | 2.532 | 58.769 | 25.214 | 1.00 | 15.93 | E | C |
| ATOM | 10298 | O | GLU | E | 735 | 3.736 | 58.508 | 25.264 | 1.00 | 16.03 | E | O |
| ATOM | 10299 | N | LEU | E | 736 | 1.636 | 57.908 | 24.748 | 1.00 | 16.58 | E | N |
| ATOM | 10300 | CA | LEU | E | 736 | 2.040 | 56.603 | 24.248 | 1.00 | 16.66 | E | C |
| ATOM | 10301 | CB | LEU | E | 736 | 0.799 | 55.750 | 23.947 | 1.00 | 15.62 | E | C |
| ATOM | 10302 | CG | LEU | E | 736 | 0.027 | 55.225 | 25.167 | 1.00 | 16.42 | E | C |
| ATOM | 10303 | CD1 | LEU | E | 736 | −1.340 | 54.738 | 24.719 | 1.00 | 13.95 | E | C |
| ATOM | 10304 | CD2 | LEU | E | 736 | 0.815 | 54.099 | 25.860 | 1.00 | 13.53 | E | C |
| ATOM | 10305 | C | LEU | E | 736 | 2.885 | 56.771 | 22.980 | 1.00 | 17.96 | E | C |
| ATOM | 10306 | O | LEU | E | 736 | 3.902 | 56.097 | 22.799 | 1.00 | 19.82 | E | O |
| ATOM | 10307 | N | ASN | E | 737 | 2.467 | 57.685 | 22.113 | 1.00 | 18.21 | E | N |
| ATOM | 10308 | CA | ASN | E | 737 | 3.176 | 57.936 | 20.863 | 1.00 | 18.85 | E | C |
| ATOM | 10309 | CB | ASN | E | 737 | 2.427 | 58.981 | 20.038 | 1.00 | 19.16 | E | C |
| ATOM | 10310 | CG | ASN | E | 737 | 2.970 | 59.103 | 18.643 | 1.00 | 19.55 | E | C |
| ATOM | 10311 | OD1 | ASN | E | 737 | 2.885 | 58.167 | 17.857 | 1.00 | 24.53 | E | O |
| ATOM | 10312 | ND2 | ASN | E | 737 | 3.540 | 60.255 | 18.325 | 1.00 | 18.87 | E | N |
| ATOM | 10313 | C | ASN | E | 737 | 4.610 | 58.403 | 21.083 | 1.00 | 20.33 | E | C |
| ATOM | 10314 | O | ASN | E | 737 | 5.514 | 58.046 | 20.315 | 1.00 | 20.89 | E | O |
| ATOM | 10315 | N | LEU | E | 738 | 4.817 | 59.203 | 22.125 | 1.00 | 17.88 | E | N |
| ATOM | 10316 | CA | LEU | E | 738 | 6.149 | 59.711 | 22.431 | 1.00 | 18.83 | E | C |
| ATOM | 10317 | CB | LEU | E | 738 | 6.121 | 60.553 | 23.709 | 1.00 | 16.70 | E | C |
| ATOM | 10318 | CG | LEU | E | 738 | 5.555 | 61.971 | 23.582 | 1.00 | 16.99 | E | C |
| ATOM | 10319 | CD1 | LEU | E | 738 | 5.434 | 62.609 | 24.960 | 1.00 | 15.04 | E | C |
| ATOM | 10320 | CD2 | LEU | E | 738 | 6.458 | 62.800 | 22.700 | 1.00 | 13.91 | E | C |
| ATOM | 10321 | C | LEU | E | 738 | 7.146 | 58.572 | 22.593 | 1.00 | 19.19 | E | C |
| ATOM | 10322 | O | LEU | E | 738 | 8.302 | 58.690 | 22.195 | 1.00 | 18.88 | E | O |
| ATOM | 10323 | N | ILE | E | 739 | 6.693 | 57.468 | 23.178 | 1.00 | 19.65 | E | N |
| ATOM | 10324 | CA | ILE | E | 739 | 7.556 | 56.318 | 23.391 | 1.00 | 20.90 | E | C |
| ATOM | 10325 | CB | ILE | E | 739 | 6.915 | 55.304 | 24.363 | 1.00 | 21.49 | E | C |
| ATOM | 10326 | CG2 | ILE | E | 739 | 7.730 | 54.006 | 24.383 | 1.00 | 19.43 | E | C |
| ATOM | 10327 | CG1 | ILE | E | 739 | 6.838 | 55.912 | 25.767 | 1.00 | 22.60 | E | C |
| ATOM | 10328 | CD1 | ILE | E | 739 | 5.598 | 55.505 | 26.556 | 1.00 | 23.07 | E | C |
| ATOM | 10329 | C | ILE | E | 739 | 7.839 | 55.623 | 22.072 | 1.00 | 21.48 | E | C |
| ATOM | 10330 | O | ILE | E | 739 | 8.971 | 55.224 | 21.805 | 1.00 | 21.63 | E | O |
| ATOM | 10331 | N | ALA | E | 740 | 6.801 | 55.475 | 21.256 | 1.00 | 23.11 | E | N |
| ATOM | 10332 | CA | ALA | E | 740 | 6.934 | 54.829 | 19.954 | 1.00 | 23.75 | E | C |
| ATOM | 10333 | CB | ALA | E | 740 | 5.582 | 54.784 | 19.246 | 1.00 | 21.82 | E | C |
| ATOM | 10334 | C | ALA | E | 740 | 7.943 | 55.591 | 19.105 | 1.00 | 23.64 | E | C |
| ATOM | 10335 | O | ALA | E | 740 | 8.799 | 54.991 | 18.460 | 1.00 | 24.11 | E | O |
| ATOM | 10336 | N | GLU | E | 741 | 7.850 | 56.915 | 19.115 | 1.00 | 24.16 | E | N |
| ATOM | 10337 | CA | GLU | E | 741 | 8.768 | 57.725 | 18.326 | 1.00 | 26.52 | E | C |
| ATOM | 10338 | CB | GLU | E | 741 | 8.360 | 59.199 | 18.382 | 1.00 | 27.95 | E | C |
| ATOM | 10339 | CG | GLU | E | 741 | 6.948 | 59.472 | 17.888 | 1.00 | 33.75 | E | C |
| ATOM | 10340 | CD | GLU | E | 741 | 6.863 | 59.586 | 16.373 | 1.00 | 36.43 | E | C |
| ATOM | 10341 | OE1 | GLU | E | 741 | 5.959 | 58.962 | 15.769 | 1.00 | 36.64 | E | O |
| ATOM | 10342 | OE2 | GLU | E | 741 | 7.703 | 60.301 | 15.787 | 1.00 | 38.56 | E | O |
| ATOM | 10343 | C | GLU | E | 741 | 10.205 | 57.567 | 18.822 | 1.00 | 26.52 | E | C |
| ATOM | 10344 | O | GLU | E | 741 | 11.146 | 57.584 | 18.037 | 1.00 | 27.58 | E | O |
| ATOM | 10345 | N | GLY | E | 742 | 10.370 | 57.404 | 20.128 | 1.00 | 26.90 | E | N |
| ATOM | 10346 | CA | GLY | E | 742 | 11.700 | 57.262 | 20.685 | 1.00 | 28.25 | E | C |
| ATOM | 10347 | C | GLY | E | 742 | 12.360 | 55.957 | 20.293 | 1.00 | 30.89 | E | C |
| ATOM | 10348 | O | GLY | E | 742 | 13.576 | 55.800 | 20.416 | 1.00 | 31.37 | E | O |
| ATOM | 10349 | N | LEU | E | 743 | 11.552 | 55.017 | 19.818 | 1.00 | 32.42 | E | N |
| ATOM | 10350 | CA | LEU | E | 743 | 12.033 | 53.705 | 19.407 | 1.00 | 32.64 | E | C |
| ATOM | 10351 | CB | LEU | E | 743 | 11.110 | 52.625 | 19.974 | 1.00 | 30.09 | E | C |
| ATOM | 10352 | CG | LEU | E | 743 | 11.462 | 51.912 | 21.286 | 1.00 | 30.54 | E | C |
| ATOM | 10353 | CD1 | LEU | E | 743 | 12.524 | 52.672 | 22.060 | 1.00 | 28.68 | E | C |
| ATOM | 10354 | CD2 | LEU | E | 743 | 10.192 | 51.759 | 22.106 | 1.00 | 28.37 | E | C |
| ATOM | 10355 | C | LEU | E | 743 | 12.048 | 53.607 | 17.884 | 1.00 | 35.10 | E | C |
| ATOM | 10356 | O | LEU | E | 743 | 12.603 | 52.667 | 17.316 | 1.00 | 35.23 | E | O |
| ATOM | 10357 | N | LYS | E | 744 | 11.432 | 54.590 | 17.237 | 1.00 | 37.67 | E | N |
| ATOM | 10358 | CA | LYS | E | 744 | 11.317 | 54.642 | 15.782 | 1.00 | 40.13 | E | C |
| ATOM | 10359 | CB | LYS | E | 744 | 10.507 | 55.876 | 15.381 | 1.00 | 38.95 | E | C |
| ATOM | 10360 | CG | LYS | E | 744 | 9.333 | 55.589 | 14.472 | 1.00 | 37.81 | E | C |
| ATOM | 10361 | CD | LYS | E | 744 | 9.204 | 56.662 | 13.416 | 1.00 | 37.70 | E | C |
| ATOM | 10362 | CE | LYS | E | 744 | 7.756 | 56.890 | 13.033 | 1.00 | 38.39 | E | C |
| ATOM | 10363 | NZ | LYS | E | 744 | 7.625 | 58.054 | 12.117 | 1.00 | 37.82 | E | N |
| ATOM | 10364 | C | LYS | E | 744 | 12.631 | 54.635 | 15.003 | 1.00 | 43.89 | E | C |
| ATOM | 10365 | O | LYS | E | 744 | 13.657 | 55.145 | 15.466 | 1.00 | 44.13 | E | O |
| ATOM | 10366 | N | SER | E | 745 | 12.576 | 54.054 | 13.807 | 1.00 | 47.80 | E | N |
| ATOM | 10367 | CA | SER | E | 745 | 13.726 | 53.969 | 12.912 | 1.00 | 51.58 | E | C |
| ATOM | 10368 | CB | SER | E | 745 | 14.854 | 53.160 | 13.559 | 1.00 | 52.07 | E | C |
| ATOM | 10369 | OG | SER | E | 745 | 16.117 | 53.664 | 13.164 | 1.00 | 54.23 | E | O |
| ATOM | 10370 | C | SER | E | 745 | 13.310 | 53.313 | 11.599 | 1.00 | 53.07 | E | C |
| ATOM | 10371 | O | SER | E | 745 | 13.454 | 52.073 | 11.489 | 1.00 | 55.17 | E | O |
| ATOM | 10372 | OT | SER | E | 745 | 12.838 | 54.045 | 10.698 | 1.00 | 54.74 | E | O |
| ATOM | 10373 | ZN | ZN | Y | 895 | 26.282 | 64.481 | 54.459 | 1.00 | 21.84 | Y | |
| ATOM | 10374 | ZN | ZN | Z | 896 | −10.532 | 48.633 | 52.392 | 1.00 | 10.96 | Z | |
| ATOM | 10375 | C1 | UK- | M | 96 | 28.708 | 61.507 | 50.251 | 1.00 | 27.31 | M | C |
| ATOM | 10376 | N2 | UK- | M | 96 | 27.930 | 62.622 | 50.777 | 1.00 | 26.26 | M | N |
| ATOM | 10377 | C6 | UK- | M | 96 | 26.525 | 62.579 | 51.248 | 1.00 | 26.94 | M | C |
| ATOM | 10378 | N3 | UK- | M | 96 | 25.847 | 61.268 | 51.484 | 1.00 | 24.41 | M | N |
| ATOM | 10379 | C7 | UK- | M | 96 | 24.495 | 61.071 | 51.571 | 1.00 | 24.32 | M | C |
| ATOM | 10380 | N4 | UK- | M | 96 | 23.456 | 62.021 | 51.856 | 1.00 | 25.77 | M | N |
| ATOM | 10381 | C9 | UK- | M | 96 | 23.547 | 63.395 | 51.311 | 1.00 | 27.36 | M | C |
| ATOM | 10382 | C10 | UK- | M | 96 | 24.659 | 64.306 | 51.874 | 1.00 | 27.58 | M | C |
| ATOM | 10383 | O7 | UK- | M | 96 | 24.552 | 64.350 | 53.313 | 1.00 | 28.39 | M | O |
| ATOM | 10384 | C11 | UK- | M | 96 | 26.033 | 63.844 | 51.414 | 1.00 | 26.47 | M | C |
| ATOM | 10385 | N1 | UK- | M | 96 | 27.040 | 64.773 | 50.852 | 1.00 | 25.27 | M | N |
| ATOM | 10386 | C2 | UK- | M | 96 | 28.038 | 63.990 | 50.403 | 1.00 | 25.08 | M | C |
| ATOM | 10387 | C3 | UK- | M | 96 | 28.708 | 61.289 | 48.728 | 1.00 | 31.05 | M | C |
| ATOM | 10388 | C12 | UK- | M | 96 | 31.021 | 60.403 | 48.195 | 1.00 | 31.23 | M | C |
| ATOM | 10389 | C18 | UK- | M | 96 | 29.618 | 60.158 | 48.266 | 1.00 | 30.19 | M | C |
| ATOM | 10390 | C19 | UK- | M | 96 | 29.116 | 58.844 | 47.883 | 1.00 | 29.62 | M | C |
| ATOM | 10391 | C4 | UK- | M | 96 | 30.057 | 57.820 | 47.437 | 1.00 | 30.03 | M | C |
| ATOM | 10392 | C5 | UK- | M | 96 | 31.467 | 58.097 | 47.376 | 1.00 | 30.94 | M | C |
| ATOM | 10393 | C13 | UK- | M | 96 | 31.952 | 59.395 | 47.762 | 1.00 | 33.18 | M | C |
| ATOM | 10394 | C14 | UK- | M | 96 | 27.705 | 58.503 | 47.930 | 1.00 | 28.59 | M | C |
| ATOM | 10395 | C8 | UK- | M | 96 | 27.256 | 57.212 | 47.546 | 1.00 | 27.38 | M | C |
| ATOM | 10396 | C15 | UK- | M | 96 | 28.190 | 56.233 | 47.109 | 1.00 | 28.76 | M | C |
| ATOM | 10397 | C16 | UK- | M | 96 | 29.586 | 56.525 | 47.051 | 1.00 | 29.01 | M | C |
| ATOM | 10398 | C17 | UK- | M | 96 | 33.403 | 59.700 | 47.717 | 1.00 | 35.16 | M | C |
| ATOM | 10399 | O1 | UK- | M | 96 | 34.141 | 59.067 | 46.947 | 1.00 | 38.94 | M | O |
| ATOM | 10400 | O2 | UK- | M | 96 | 33.837 | 60.583 | 48.471 | 1.00 | 37.40 | M | O |
| ATOM | 10401 | C1 | UK- | N | 96 | −10.631 | 45.024 | 56.751 | 1.00 | 33.13 | N | C |
| ATOM | 10402 | N2 | UK- | N | 96 | −10.531 | 46.395 | 56.218 | 1.00 | 31.91 | N | N |
| ATOM | 10403 | C6 | UK- | N | 96 | −9.330 | 47.099 | 55.692 | 1.00 | 33.27 | N | C |
| ATOM | 10404 | N3 | UK- | N | 96 | −8.016 | 46.398 | 55.613 | 1.00 | 31.29 | N | N |
| ATOM | 10405 | C7 | UK- | N | 96 | −6.815 | 47.013 | 55.436 | 1.00 | 30.25 | N | C |
| ATOM | 10406 | N4 | UK- | N | 96 | −6.561 | 48.232 | 54.747 | 1.00 | 28.61 | N | N |
| ATOM | 10407 | C9 | UK- | N | 96 | −7.304 | 49.425 | 55.161 | 1.00 | 29.57 | N | C |
| ATOM | 10408 | C10 | UK- | N | 96 | −8.795 | 49.509 | 54.727 | 1.00 | 31.61 | N | C |
| ATOM | 10409 | O7 | UK- | N | 96 | −8.858 | 49.507 | 53.294 | 1.00 | 29.31 | N | O |
| ATOM | 10410 | C11 | UK- | N | 96 | −9.651 | 48.386 | 55.327 | 1.00 | 32.62 | N | C |
| ATOM | 10411 | N1 | UK- | N | 96 | −11.027 | 48.634 | 35.831 | 1.00 | 32.56 | N | N |
| ATOM | 10412 | C2 | UK- | N | 96 | −11.401 | 47.491 | 56.444 | 1.00 | 32.80 | N | C |
| ATOM | 10413 | C3 | UK- | N | 96 | −10.318 | 44.790 | 58.252 | 1.00 | 34.74 | N | C |
| ATOM | 10414 | C12 | UK- | N | 96 | −11.053 | 42.381 | 58.745 | 1.00 | 34.61 | N | C |
| ATOM | 10415 | C18 | UK- | N | 96 | −9.985 | 43.324 | 58.623 | 1.00 | 33.91 | N | C |
| ATOM | 10416 | C19 | UK- | N | 96 | −8.620 | 42.858 | 58.871 | 1.00 | 32.94 | N | C |
| ATOM | 10417 | C4 | UK- | N | 96 | −8.380 | 41.461 | 59.233 | 1.00 | 32.47 | N | C |
| ATOM | 10418 | C5 | UK- | N | 96 | −9.484 | 40.537 | 59.347 | 1.00 | 35.83 | N | C |
| ATOM | 10419 | C13 | UK- | N | 96 | −10.829 | 41.002 | 59.098 | 1.00 | 36.61 | N | C |
| ATOM | 10420 | C14 | UK- | N | 96 | −7.474 | 43.743 | 58.768 | 1.00 | 32.55 | N | C |
| ATOM | 10421 | C8 | UK- | N | 96 | −6.157 | 43.264 | 59.014 | 1.00 | 32.86 | N | C |
| ATOM | 10422 | C15 | UK- | N | 96 | −5.942 | 41.895 | 59.371 | 1.00 | 32.47 | N | C |
| ATOM | 10423 | C16 | UK- | N | 96 | −7.048 | 40.992 | 59.482 | 1.00 | 32.05 | N | C |
| ATOM | 10424 | C17 | UK- | N | 96 | −11.985 | 40.068 | 59.199 | 1.00 | 38.95 | N | C |
| ATOM | 10425 | O1 | UK- | N | 96 | −12.017 | 39.202 | 60.107 | 1.00 | 40.94 | N | O |
| ATOM | 10426 | O2 | UK- | N | 96 | −12.897 | 40.189 | 58.356 | 1.00 | 41.04 | N | O |
| END | | | | | | | | | | | | |

1. An AMP deaminase (AMPDA) crystal, wherein said crystal is tetragonal.

2. The crystal of claim 1, wherein said crystal consists essentially of the catalytic domain of AMPDA.

3. The crystal of claim 1, wherein said AMPDA is from a mammal.

4. The crystal of claim 3, wherein the AMPDA is from a rabbit.

5. The crystal of claim 4, wherein the sequence of said AMPDA consists essentially of amino acids 96-747 of SEQ ID NO: 2.

6. The crystal of claim 1, wherein said crystal is grown using citric acid as a precipitating agent.

7. The crystal of claim 1, wherein said crystal is grown in the pH range of 7.80-8.20.

8. The crystal of claim 1, wherein said crystal is grown in the presence of imidazole.

9. The crystal of claim 1, wherein said crystal has a space group P4₂2₁2.

10. The crystal of claim 1, wherein said crystal has unit cell dimensions of a=b=149 Å +/−3 Å, c=159 Å+/−3 Å.

11. The crystal of claim 1, wherein the active site of said AMPDA is contained in a cleft formed by additional helices between first and second strands of a (βα)₈ barrel fold, and a helix immediately following a third strand.

12. The crystal of claim 1, wherein said AMPDA has a pocket which can accommodate the adenosine group of AMP, which pocket is formed by amino acid residues including residues His305, Phe372, Phe375, Asp513, Glu575, His594, and Asp650.

13. The crystal of claim 1, wherein said AMPDA has a pocket which can accommodate the ribose and phosphate groups of AMP, which pocket is formed by amino acid residues His305, Ala306, Ala307, Ala308, Phe375, Asn376, Tyr379, Arg388, Lys393, Ser427, Tyr429, Pro460, Ile462, Val512, and Asp513.

14. The crystal of claim 1, wherein said crystal diffracts X-rays to 3.5 Å or higher resolution.

15. The crystal of claim 1 further comprising heavy metal atoms.

16. The crystal of claim 1 further comprising an AMPDA inhibitor that has been soaked into said crystal.

17. The crystal of claim 16, wherein said inhibitor is an AMPDA transition state analogue.

18. The crystal of claim 17, wherein said inhibitor is a cofornycin analogue.

19. The crystal of claim 18, wherein said inhibitor is cofonnycin or 3-(2′-(3″-carboxynaphthyl) ethyl)coformycin aglycone.

20. The crystal of claim 1, wherein the primary sequence of said AMPDA has 90% or higher identity at the amino acid level to the sequence shown in SEQ ID NO:2.

21. A method of selecting an AMPDA inhibitor compound from a group of potential AMPDA inhibitor compounds, comprising the following steps:
a) creating a three-dimensional representation of the structure of AMPDA;
b) displaying and superimposing a model of said potential AMPDA inhibitor compound on said representation of the AMPDA structure; and
c) assessing whether said potential AMPDA inhibitor compound model fits said representation of the AMPDA structure.

22. The method of claim 21, further comprising the following steps:
d) incorporating said potential AMPDA inhibitor compound in a biological AMPDA activity assay; and
e) determining whether said potential AMPDA inhibitor compound inhibits AMPDA activity in said assay.

23. A method of selecting an AMPDA inhibitor compound from a group of potential AMPDA inhibitor compounds, comprising the following steps:
a) creating a three-dimensional representation of the active site cavity of AMPDA;
b) displaying and superimposing a model of said potential AMPDA inhibitor compound on said representation of the active site cavity;
c) assessing whether said potential AMPDA inhibitor compound model fits the active site.

24. An isolated and/or purified AMPDA polynucleotide selected from the group consisting of:
a) a polynucleotide encoding the polypeptide as set forth in SEQ ID NO: 2;
b) a polynucleotide comprising the nucleotide sequence of SEQ ID NO: 1;
c) a polynucleotide comprising a nucleotide sequence that has at least 91% identity to the polynucleotide of any one of (a) or (b);
d) a polynucleotide comprising a nucleotide sequence that has at least 95% identity to the polynucleotide of any one of (a) or (b);
e) a polynucleotide comprising a nucleotide sequence which is capable of hybridising to the polynucleotide of any one of (a) or (b) under high stringency conditions;
f) a complement to the polynucleotide of any one of (a) to (e); and
g) a polynucleotide fragment of the polynucleotide of any one of (a) to (f).

25. An AMPDA polypeptide selected from the group consisting of:
a) a polypeptide having the deduced amino acid sequence translated from the polynucleotide sequence in SEQ ID NO: 1 and variants, fragments, homologues, analogues and derivatives thereof; and
b) a polypeptide of SEQ ID NO: 2 and variants, fragments, homologues, analogues and derivatives thereof.


SEQUENCE LISTING (6 sequences)

SEQ ID NO: 1 - DNA, 2241 bp, Oryctolagus cuniculus (Rabbit)
atgcctctgttcaaactcccagctgaaggaaaagaactcgatgatgcaatgggcagcttcgctgaaaaagtgtttgcctcagaagtcaaagatgaggggggccgccaggagatttccccttttgatgtggatgagatctgtccaatttctcatcatgagatgcaagcgcacatactccacatggagacgctggccacctccccagaaggcacgaggaaaaagcgtttccaaggacggaagactgttaatttgtccattccactcagtgaagcatcttccaccaaactgtcgcacattgatgaatacatctctttatctccaacctaccagacagtccctgattttcagagagtgcagatcacgggagactatgcctctggggtcacagtggaagacttcgaaatagtgtgcaaagggctgtaccgggcattgtgtatccgggagaaatacatgctgaagtcgtttcagaggttccccaaaaccccttccaagtacttgcggagcattgaaggcacagcttggaaagcaaatgagagctcctatccagtctttacacctgctctgaagaagggagaggaccctttccgaacagacaacctgcccgaaaacctgggctatcacctcaaaatgaaagacggtgtggtttacatctatgctaacgaagcagcagcgggcaaagatgagcccaagccacttctttacccaaatatggaggagttcttggatgatatgaattttttgcttgctttaattgcccaaggacctgttaagacctatacgcaccggcgtctgaagttcctctcctccaagttccaggtgcaccagatgctcaacgagatggacgagctgaaggagctgaagaacaaccctcaccgcgatttttacaactgcaggaaggtggacacccacatccatgcagctgcctgcatgaaccagaaacatctgctgcgcttcattaagaaatcttaccaagtggatgccgacagagtggtctacagcaccaaagagaagaatctaaccctaaagcaactttttgataaattaaaactgcacccctatgacctgactgtcgactctctggatgttcatgccggccgccagaccttccagcgttttgataagttcaatgacaaatacaatcctgtaggagcaagtgagctgcgggatctctacctgaagacagacaattacattaacggggaatattttgccactatcatcaaggaggtaggtgcagacttggtggacgccaagtaccagcatgctgagcctcgtctgtccatctatggccgcagccctgatgagtggagcaaactttcctcctggttcgtccgcaaccgcatctacagctctaacatgacatggatgatccaggtccccaggatctatgatgtgtttcgatccaagaatttccttccacacttcggaaagatgctggagaatgtgttcatgccagtgtttgaggcgaccatcaacccccaagctcatccagaactcagtgtctttcttaaacatatcactggctttgacagtgtggatgatgaaagtaaacacagtggccatatgttttcttcaaaaagccccaaaccccaggagtggaccttggaaaaaaatccttcctatacctactacgcctactacatgtatgcaaacatcatggtgctcaacagcctgagaaaggaacgaggcatgaatacatttctgttccgacctcactgcggggaagttggggctctcacccacctcatgaccgccttcatgacagcagataatatctctcatggcctgaatttaaaaaagagtcctgtgttacaatacttgtttttcttagcccagattcctatcgccatgtcaccattaagtaacaacagcctatttctagagtatgccaaaaatccatttttagattttctccagaaaggactaatgatctcactgtctaccgatgatccgatgcagttccacttcaccaaggagcccctgatggaagaatacgccattgcagcacaagtcttcaagctgagtacctgtgacatgtgtgaagtggcgaggaacagtgttctgcagtgtggaatttctcatgaggaaaaagcaaagtttttgggcaacaattaccttgaggaaggccccattggaaatgatatccggaagacgaatgtagcccaaatccgcatggcctatcgctatgaaacctggtgttatgaactcaatttaattgctgagggtcttaaatcaacagaa

SEQ ID NO: 2 - protein, 747 aa, Oryctolagus cuniculus (Rabbit)
MPLFKLPAEGKELDDAMGSFAEKVFASEVKDEGGRQEISPFDVDEICPISHHEMQAHILHMETLATSPEGTRKKRFQGRKTVNLSIPLSEASSTKLSHIDEYISLSPTYQTVPDFQRVQITGDYASGVTVEDFEIVCKGLYRALCIREKYMLKSFQRFPKTPSKYLRSIEGTAWKANESSYPVFTPALKKGEDPFRTDNLPENLGYHLKMKDGVVYIYANEAAAGKDEPKPLLYPNMEEFLDDMNFLLALIAQGPVKTYTHRRLKFLSSKFQVHQMLNEMDELKELKNNPHRDFYNCRKVDTHIHAAACMNQKHLLRFIKKSYQVDADRVVYSTKEKNLTLKQLFDKLKLHPYDLTVDSLDVHAGRQTFQRFDKFNDKYNPVGASELRDLYLKTDNYINGEYFATIIKEVGADLVDAKYQHAEPRLSIYGRSPDEWSKLSSWFVRNRIYSSNMTWMIQVPRIYDVFRSKNFLPHFGKMLENVFMPVFEATINPQAHPELSVFLKHITGFDSVDDESKHSGHMFSSKSPKPQEWTLEKNPSYTYYAYYMYANIMVLNSLRKERGMNTFLFRPHCGEVGALTHLMTAFMTADNISHGLNLKKSPVLQYLFFLAQIPIAMSPLSNNSLFLEYAKNPFLDFLQKGLMISLSTDDPMQFHFTKEPLMEEYAIAAQVFKLSTCDMCEVARNSVLQCGISHEEKAKFLGNNYLEEGPIGNDIRKTNVAQIRMAYRYETWCYELNLIAEGLKSTE

SEQ ID NO: 3 - DNA, 20 bp, Homo sapiens
atgcctctgttcaaactccc

SEQ ID NO: 4 - DNA, 21 bp, Homo sapiens
ttctgttgatttaagaccctc

SEQ ID NO: 5 - DNA, 21 bp, Homo sapiens
atgaaccagaaacatctgctg

SEQ ID NO: 6 - DNA, 22 bp, Homo sapiens
cagcagatgtttctggttcatg